(19) United States
(12) Patent Application Publication
(10) Pub. No.: US 2023/0200102 A1
(43) Pub. Date: Jun. 22, 2023

(54) MIXED LAYER, METHOD OF PREPARING THE MIXED LAYER, LIGHT-EMITTING DEVICE, AND ELECTRONIC APPARATUS

(71) Applicant: Samsung Electronics Co., Ltd., Suwon-si (KR)

(72) Inventors: Sunghun Lee, Hwaseong-si (KR); Seungyeon Kwak, Suwon-si (KR); Myungsun Sim, Suwon-si (KR)

(21) Appl. No.: 18/067,111

(22) Filed: Dec. 16, 2022

(30) Foreign Application Priority Data
Dec. 17, 2021 (KR) 10-2021-0181735

(51) Int. Cl. H10K 50/155; H10K 50/165; H10K 50/12; H10K 50/125; H10K 71/16; H10K 71/30

(52) U.S. Cl. CPC H10K 50/155; H10K 50/165; H10K 50/12; H10K 50/125; H10K 71/16; H10K 71/30

(57) ABSTRACT

A mixed layer including: a matrix material; and a dopant composition, wherein the dopant composition is doped in the matrix material, the dopant composition comprises a first dopant and a second dopant, an amount by weight of the matrix material is greater than an amount by weight of the dopant composition in the mixed layer, the matrix material, the first dopant, and the second dopant are different from each other, the matrix material does not include a transition metal, the first dopant includes a transition metal, the mixed layer is a layer formed by deposition of the matrix material, the first dopant, and the second dopant, the mixed layer has a concentration profile of the dopant composition with respect to a thickness of the mixed layer, provided that Tₘ₁>Tₚ>Tₘ₁₊₂ is satisfied, wherein Tₘ₁, Tₚ, and Tₘ₁₊₂ are respectively as described herein.

### CROSS-REFERENCE TO RELATED APPLICATION

This application is based on and claims priority to Korean Patent Application No. 10-2021-0181735, filed on Dec. 17, 2021, in the Korean Intellectual Property Office, and all the benefits accruing therefrom under 35 U.S.C. § 119, the content of which is incorporated by reference herein in its entirety.

### BACKGROUND

### 1. Field

The present disclosure relates to a mixed layer, a method of preparing the mixed layer, a light-emitting device including the mixed layer, and an electronic apparatus including the light-emitting device.

### 2. Description of the Related Art

From among light-emitting devices, organic light-emitting devices (OLEDs) are self-emissive devices, which have improved characteristics in terms of viewing angles, response time, luminance, driving voltage, and response speed. In addition, OLEDs may produce full-color images.

In an example, an organic light-emitting device includes an anode, a cathode, and an organic layer arranged between the anode and the cathode, wherein the organic layer includes an emission layer. A hole transport region may be located between the anode and the emission layer, and an electron transport region may be located between the emission layer and the cathode. Holes provided from the anode move toward the emission layer through the hole transport region, and electrons provided from the cathode move toward the emission layer through the electron transport region. The holes and the electrons recombine in the emission layer to produce excitons. These excitons transition from an excited state to a ground state, thereby generating light.

### SUMMARY

Provided are a mixed layer in which a first dopant and a second dopant are effectively doped at substantially the same time (e.g., at the same time) without thermal denaturation, a light-emitting device having excellent luminescence efficiency and/or a long lifespan by including the mixed layer, and an electronic apparatus including the light-emitting device. In addition, provided is a method of preparing a mixed layer, the method being capable of providing excellent process stability and reduction in manufacturing costs.

Additional aspects will be set forth in part in the detailed description which follows and, in part, will be apparent from the detailed description, or may be learned by practice of the exemplary embodiments of the detailed description.

According to an aspect, provided is a mixed layer including:
a matrix material; and
a dopant composition,
wherein the dopant composition is doped in the matrix material,
wherein the dopant composition comprises a first dopant and a second dopant,
an amount by weight of the matrix material in the mixed layer is greater than an amount by weight of the dopant composition in the mixed layer,
the matrix material, the first dopant, and the second dopant are different from each other,
the matrix material does not include a transition metal,
the first dopant includes a transition metal,
the mixed layer is a layer formed by deposition of the matrix material, the first dopant, and the second dopant,
the mixed layer has a concentration profile of the dopant composition with respect to a thickness of the mixed layer,
provided that Tₘ₁>Tₚ>Tₘ₁₊₂ is satisfied,
wherein,
Tₘ₁ is a melting point of the first dopant,
Tₚ is a deposition temperature used in forming the mixed layer, and
Tₘ₁₊₂ is:
a melting point of a pre-mixed composition of the first dopant and the second dopant wherein the pre-mixed composition is crystalline; and
a fusion temperature of the pre-mixed composition of the first dopant and the second dopant when the pre-mixed composition is amorphous,
wherein the pre-mixed composition includes the first dopant and the second dopant, and is not doped in the matrix material.

The mixed layer may be a layer formed by deposition of a vapor-state matrix material and a vapor-state dopant composition, and the vapor-state dopant composition may be a mixture of a vapor-state first dopant and a vapor-state second dopant.

The second dopant may or may not include a transition metal.

The mixed layer may be an emission layer, and
i) each of the first dopant and the second dopant may be an emitter;
ii) the first dopant may be an emitter, and the second dopant may be a sensitizer; or
iii) the first dopant may be a sensitizer, and the second dopant may be an emitter.

The mixed layer may be an emission layer, and
i) each of the first dopant and the second dopant may emit red light;
ii) each of the first dopant and the second dopant may emit green light; or
iii) each of the first dopant and the second dopant may emit blue light.

According to another aspect, provided is a method of preparing the mixed layer as described above, the method including:
preparing:
a substrate,
a first deposition source comprising the first dopant and the second dopant,
a second deposition source comprising the matrix material, and
a vapor-state dopant composition provision unit configured to provide a vapor-state dopant composition from the first deposition source, wherein the vapor-state dopant composition comprises a vapor-state first dopant and a vapor-state second dopant;
preparing a deposition source moving unit on which the first deposition source and the second deposition source are arranged with a distance therebetween such that a region wherein the vapor-state dopant composition is present overlaps a region wherein a vapor-state matrix material is present, the vapor-state matrix material being released from the second deposition source;
arranging the deposition source moving unit at a first end below a surface of the substrate such that the substrate faces the deposition source moving unit; and
depositing the matrix material, the first dopant, and the second dopant on the surface of the substrate by:
performing a one-way process of moving the deposition source moving unit in a direction away from the first end below the surface of the substrate and toward a second end, or
performing, one or more times, a reciprocating process of moving the deposition source moving unit in a direction away from the first end below the surface of the substrate and toward a second end, and then immediately moving the deposition source moving unit in a direction away from the second end and toward the first end,
wherein the first deposition source includes a first region and a second region, wherein the first region comprises the first dopant and does not comprise the second dopant, and wherein the second region comprises the second dopant and does not comprise the first dopant, wherein the first dopant and the second dopant in the first deposition source are not mixed with each other.

The vapor-state dopant composition provision unit may include:
a first unit configured to form the vapor-state dopant composition; and
a second unit configured to discharge the vapor-state dopant composition from the first unit.

A deposition temperature of the depositing may be lower than a melting point of the first dopant, and
when a pre-mixed composition of the first dopant and the second dopant is crystalline, the deposition temperature of the depositing may be higher than a melting point of the pre-mixed composition, and
when the pre-mixed composition of the first dopant and the second dopant is amorphous, the deposition temperature of the depositing may be higher than a fusion temperature of the pre-mixed composition,
wherein the pre-mixed composition includes the first dopant and the second dopant, and is not doped in the matrix material.

According to still another aspect, provided is a light-emitting device including:
a first electrode;
a second electrode facing the first electrode; and
an interlayer located between the first electrode and the second electrode,
wherein the interlayer includes the mixed layer as described herein.

The mixed layer included in the light-emitting device may be an emission layer.

The interlayer may include:
m light-emitting units that include at least one emission layer; and
m−1 charge generation layers that are arranged between two neighboring light-emitting units of the m light-emitting units,
wherein m may be an integer of 2 or greater, and
at least one light-emitting unit of the m light-emitting units may include the mixed layer as described herein.

The mixed layer included in the light-emitting unit may be an emission layer.

At least one light-emitting unit of the m light-emitting units may emit green light, and at least one light-emitting unit of the remaining light-emitting units may emit blue light.

According to still another aspect, provided is an electronic apparatus including the light-emitting device.

### BRIEF DESCRIPTION OF THE DRAWINGS

The above and other aspects, features, and advantages of certain exemplary embodiments of the disclosure will be more apparent from the following detailed description and when taken in conjunction with the accompanying drawings, in which:

FIG. 1 is a diagram schematically illustrating a mixed layer according to one or more embodiments;

FIGS. 2A to 2G are diagrams sequentially illustrating a method of preparing a mixed layer, according to one or more embodiments;

FIG. 3 is a diagram illustrating one or more embodiments of a first deposition source and a vapor-state dopant composition provision unit;

FIG. 4 is a graph of concentration of dopant composition (weight percent wt %) versus thickness of the mixed layer (x, nanometers (nm)), and is a diagram illustrating one or more embodiments of a concentration profile of a dopant composition for each thickness of a mixed layer, wherein the regions indicated beneath the x-axis by 151, 153, 155, 157, and 159 correspond to those regions as labelled in FIGS. 2A to 2G;

FIGS. 5 to 9 are graphs of concentration of dopant composition (weight percent wt %) versus thickness of the mixed layer (x, nanometers (nm)), and are each a diagram illustrating one or more embodiments of a concentration profile of a dopant composition for each thickness of a mixed layer;

FIG. 10 is a graph of concentration of dopant composition (wt %) versus thickness of a layer (x, nm), and shows a diagram illustrating a comparative concentration profile of a first dopant and a concentration profile of a second dopant for each thickness of a layer B, which is formed by using each of a deposition source B1 loaded with the first dopant and a deposition source B2 loaded with the second dopant, instead of a first deposition source loaded with the first dopant and the second dopant;

FIG. 11 is a diagram schematically illustrating a light-emitting device according to one or more embodiments; and

FIG. 12 is a diagram schematically illustrating a light-emitting device according to one or more embodiments.

### DETAILED DESCRIPTION

Reference will now be made in further detail to exemplary embodiments, examples of which are illustrated in the accompanying drawings, wherein like reference numerals refer to like elements throughout. In this regard, the present exemplary embodiments may have different forms and should not be construed as being limited to the detailed descriptions set forth herein. Accordingly, the exemplary embodiments are described in further detail below, and by referring to the figures, to explain certain aspects. As used herein, the term “and/or” includes any and all combinations of one or more of the associated listed items. Expressions such as “at least one of,” when preceding a list of elements, modify the entire list of elements and do not modify the individual elements of the list.

The terminology used herein is for the purpose of describing one or more exemplary embodiments only and is not intended to be limiting. As used herein, the singular forms “a,” “an,” and “the” are intended to include the plural forms as well, unless the context clearly indicates otherwise. The term “or” means “and/or.” It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms first, second, third etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present embodiments.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

It will be understood that when an element is referred to as being “on” another element, it can be directly in contact with the other element or intervening elements may be present therebetween. In contrast, when an element is referred to as being “directly on” another element, there are no intervening elements present.

Unless otherwise defined, all terms (including technical and scientific terms) used herein have the same meaning as commonly understood by one of ordinary skill in the art to which this general inventive concept belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Hereinafter, a work function or a highest occupied molecular orbital (HOMO) energy level is expressed as an absolute value from a vacuum level. In addition, when the work function or the HOMO energy level is referred to be “deep,” “high” or “large,” the work function or the HOMO energy level has a large absolute value based on “0 electron Volts (eV)” of the vacuum level, while when the work function or the HOMO energy level is referred to be “shallow,” “low,” or “small,” the work function or HOMO energy level has a small absolute value based on “0 eV” of the vacuum level.

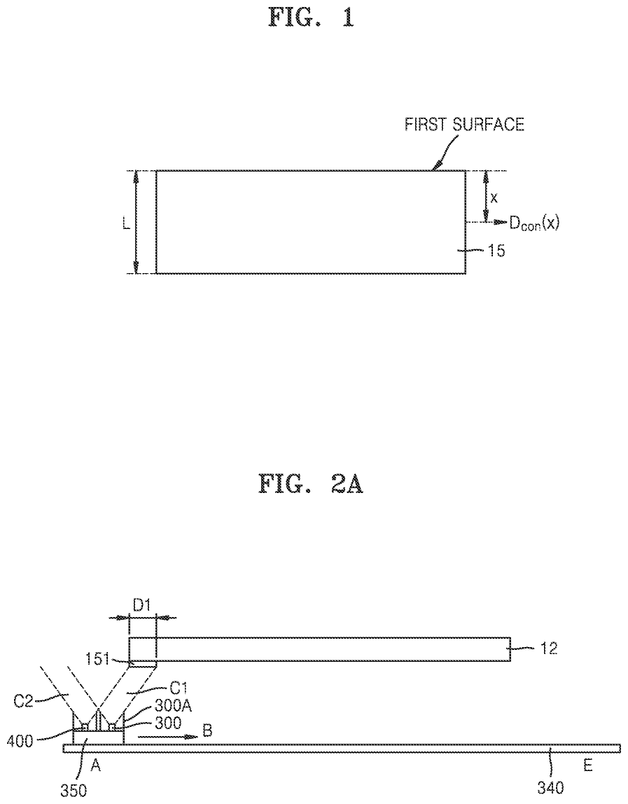

### Description of FIGS. 1, 2A to 2G, and 3 to 10

A mixed layer 15 in FIG. 1 includes a matrix material and a dopant composition.

The dopant composition is doped in the matrix material.

The dopant composition includes (e.g., may be a mixture of) a first dopant and a second dopant. The dopant composition may further include materials other than the first dopant and the second dopant.

An amount by weight of the matrix material in the mixed layer may be greater than an amount by weight of the dopant composition in the mixed layer.

For example, a weight ratio of the matrix material to the dopant composition may be in a range of about 60:40 to about 99:1, about 70:30 to about 99:1, about 80:20 to about 99:1, about 60:40 to about 95:5, about 70:30 to about 95:5, or about 80:20 to about 95:5.

The matrix material, the first dopant, and the second dopant are different from each other.

The matrix material does not include a transition metal.

For example, the matrix material may include a hole-transporting compound, an electron-transporting compound, a bipolar compound, or a combination thereof.

In one or more embodiments, the matrix material may not be an organometallic compound including a transition metal and at least one ligand bonded to the transition metal.

In one or more embodiments, the matrix material may be a mixture of a hole-transporting compound and an electron-transporting compound.

The first dopant includes a transition metal (for example, one transition metal).

For example, the first dopant may be an organometallic compound including a transition metal and at least one ligand bonded to the transition metal.

The first dopant may be electrically neutral, or have a net zero charge.

In one or more embodiments, the first dopant may include iridium or platinum.

The second dopant may or may not include a transition metal.

Each of the matrix material, the first dopant, and the second dopant will be described in further detail herein.

The mixed layer 15 may be a layer formed by deposition of the matrix material, the first dopant, and the second dopant. The deposition may be co-deposition in which the matrix material, the first dopant, and the second dopant are vaporized at substantially the same time (e.g., at the same time) and deposited on a surface of a substrate including a region in which the mixed layer 15 is to be formed. The deposition may be vacuum deposition performed under a substantially vacuum atmosphere.

x in D_{con}(x) in FIG. 1 is a real number and a variable satisfying 0≤x≤L, L in FIG. 1 indicates a thickness (constant) of the mixed layer 15, and D_{con}(x) in FIG. 1 indicates a “concentration of the dopant composition” at a position spaced apart by x from a first surface of the mixed layer 15 toward inside of the mixed layer 15, wherein D_{con}(x) indicates a weight of the dopant composition in wt % based on 100 wt % of the total weight of the matrix material and the dopant composition at the position spaced apart by x from the first surface of the mixed layer 15 toward the inside of the mixed layer 15. For example, D_{con}(x) may be in a range of about 1 wt % to about 40 wt %, about 3 wt % to about 30 wt %, or about 5 wt % to about 20 wt %.

The unit of x may be any arbitrary unit. For example, the unit of x may be nanometers (nm).

D_{con}(x) may be evaluated through material analysis for each thickness of the mixed layer 15. For example, D_{con}(x) may be evaluated using Orbitrap mass spectrometry and/or secondary ion mass spectrometry (SIMS). D_{con}(x) may be expressed as a function of the thickness of the mixed layer 15 (the variable represented by x). Accordingly, the mixed layer 15 may have a concentration profile of the dopant composition with respect to the thickness of the mixed layer 15. The concentration profile of the dopant composition in the mixed layer 15 may be discontinuous or continuous.

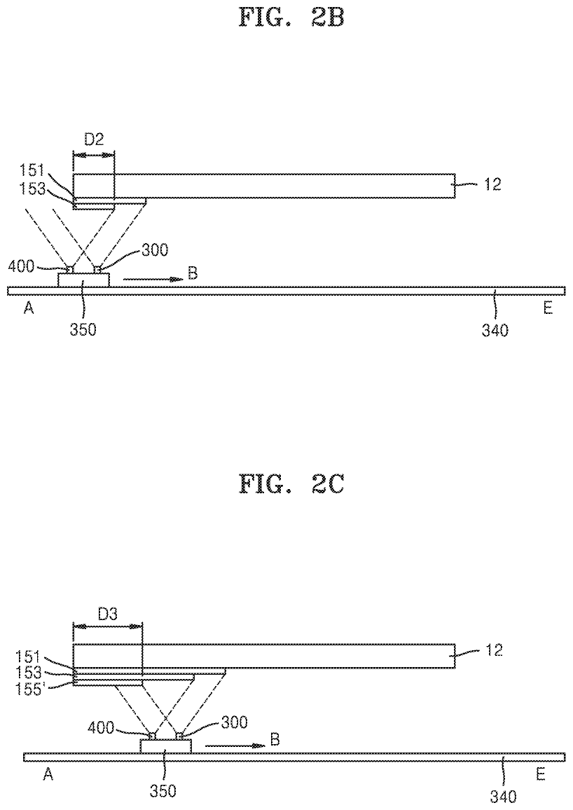

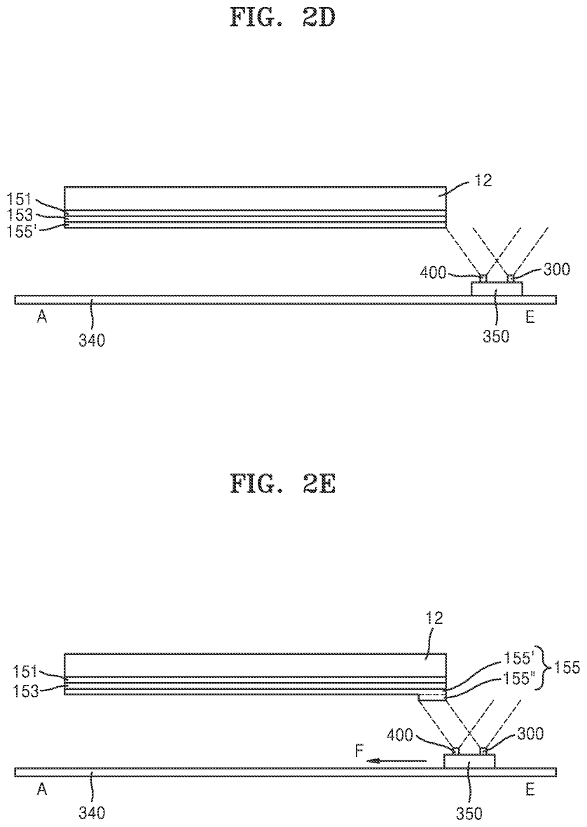

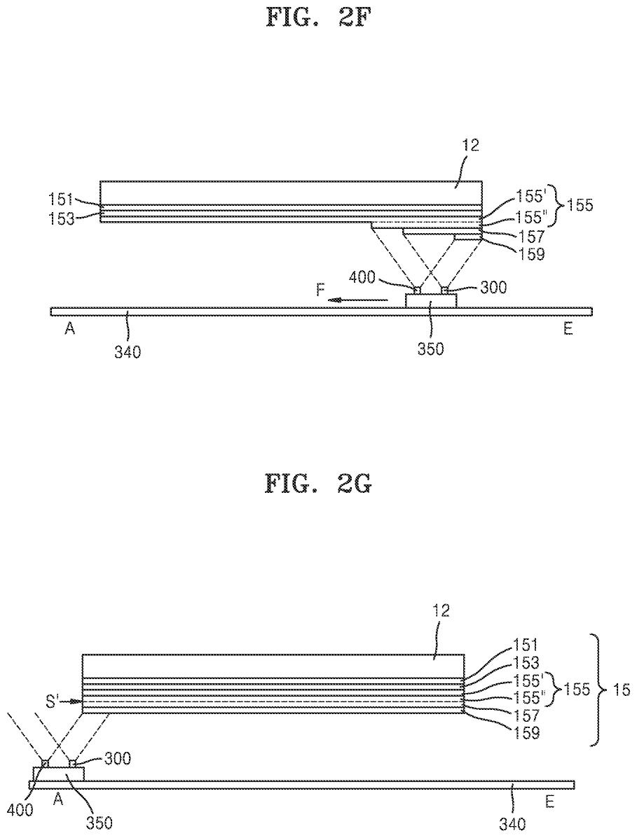

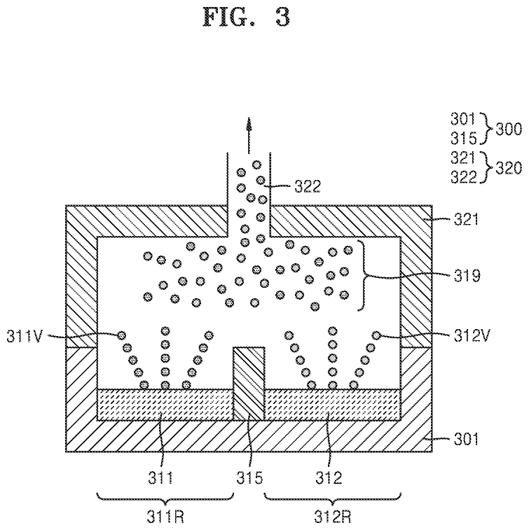

FIGS. 2A to 2G sequentially illustrate one or more embodiments of a method of forming the mixed layer 15 on a surface of a substrate 12, and FIG. 3 illustrates one or more embodiments of a first deposition source 300 and a vapor-state dopant composition provision unit 320.

First, a) the substrate 12 on which the mixed layer 15 is to be formed, b) the first deposition source 300 includes (e.g., is loaded with) the first dopant and the second dopant, c) a second deposition source 400 includes (e.g., is loaded with) the matrix material, and d) the vapor-state dopant composition provision unit 320 (not shown in FIGS. 2A to 2G) for providing a vapor-state dopant composition, which is a composition of a vapor-state first dopant and a vapor-state second dopant released from the first deposition source, are prepared.

The substrate 12 may vary according to the use of the mixed layer 15. For example, when the mixed layer 15 is an emission layer of a light-emitting device, the substrate 12 may be a hole transport region formed on a first electrode.

The first deposition source 300 includes a first region and a second region, the first region includes the first dopant and does not include the second dopant, and the second region includes the second dopant and does not include the first dopant, so that the first dopant and the second dopant loaded in the first deposition source 300 are not mixed with each other. For example, the first dopant and the second dopant loaded in the first deposition source 300 are not in contact with each other. In one or more embodiments, the first dopant and the second dopant are loaded in the first deposition source 300 and do not form a pre-mixed composition (e.g., mixture) of the first dopant and the second dopant. The first deposition source 300 may further include materials other than the first dopant and the second dopant.

For example, a solid-state block-type first dopant and a solid-state block-type second dopant obtained by pressing the first dopant and the second dopant, respectively and separately, and may be spaced apart from each other and loaded into the first deposition source 300.

In one or more embodiments, the first deposition source 300 may further include a separation unit for separating the first region and the second region. For example, the separation unit may include a blocking plate for separating the first region and the second region, individual pockets for accommodating the first dopant and the second dopant, respectively, and the like.

The second deposition source 400 is loaded with the matrix material as described herein. When the matrix material includes two or more different materials, a pre-mixed composition of the different materials may be loaded in the second deposition source 400.

The vapor-state dopant composition provision unit 320 may be installed in combination with the first deposition source 300.

FIG. 3 is a diagram schematically illustrating one or more embodiments of the first deposition source 300 and the vapor-state dopant composition provision unit 320.

The first deposition source 300 in FIG. 3 includes a tray 301 for accommodating a first dopant 311 and a second dopant 312. The tray 301 includes a first region 311R including only the first dopant 311, a second region 312R including only the second dopant 312, and a separation unit 315 (for example, a blocking plate) for dividing the first region 311R and the second region 312R. The first region 311R includes only the first dopant 311, and the second region 312R includes only the second dopant 312, so that the first dopant 311 and the second dopant 312 are not mixed with each other. In FIG. 3, instead of arranging the separation unit 315, the first dopant 311 that is solidified and the second dopant 312 that is solidified may be arranged to be spaced apart from each other.

The vapor-state dopant composition provision unit 320 includes a first unit 321 for forming a vapor-state dopant composition 319 and a second unit 322 for discharging the vapor-state dopant composition 319 from the first unit 321.

When the first deposition source 300 is turned on, a vapor-state first dopant 311V and a vapor-state second dopant 312V may be released from the first deposition source 300 to be accommodated and mixed in a space formed by the first unit 321, thereby forming the vapor-state dopant composition 319 which is a composition comprising the vapor-state first dopant 311V and the vapor-state second dopant 312V. The first unit 321 may be, for example, an inner plate as shown in FIG. 3, and by increasing internal pressure of the space formed by the first unit 321, the vapor-state first dopant 311V and the vapor-state second dopant 312V may be mixed to form the vapor-state dopant composition 319. The vapor-state dopant composition 319 may be discharged from the first unit 321 through the second unit 322 and used in a deposition process to be described below. The second unit 322 may be, for example, a nozzle or the like.

The term “pre-mixed composition of a material A and a material B” as used herein refers to a composition or mixture formed by pre-mixing the material A and the material B before forming a layer including the material A and the material B, and each of the material A and the material B may be in a solid state or a liquid state. For example, the pre-mixed composition may be prepared by a physical mixing method in which the material A and the material B are physically mixed, a sublimation mixing method in which the material A and the material B are sublimated in a sublimation purifier and then solidified, or the like.

Accordingly, the “pre-mixed composition of the first dopant and the second dopant” refers to a composition that is formed by pre-mixing the first dopant and the second dopant before forming the mixed layer 15, and thus is clearly distinguished from the “composition comprising the first dopant and the second dopant” in the mixed layer, which is a dopant composition doped in the mixed layer 15 through a deposition process. In other words, the pre-mixed composition includes the first dopant and the second dopant, and is not doped in the matrix material.

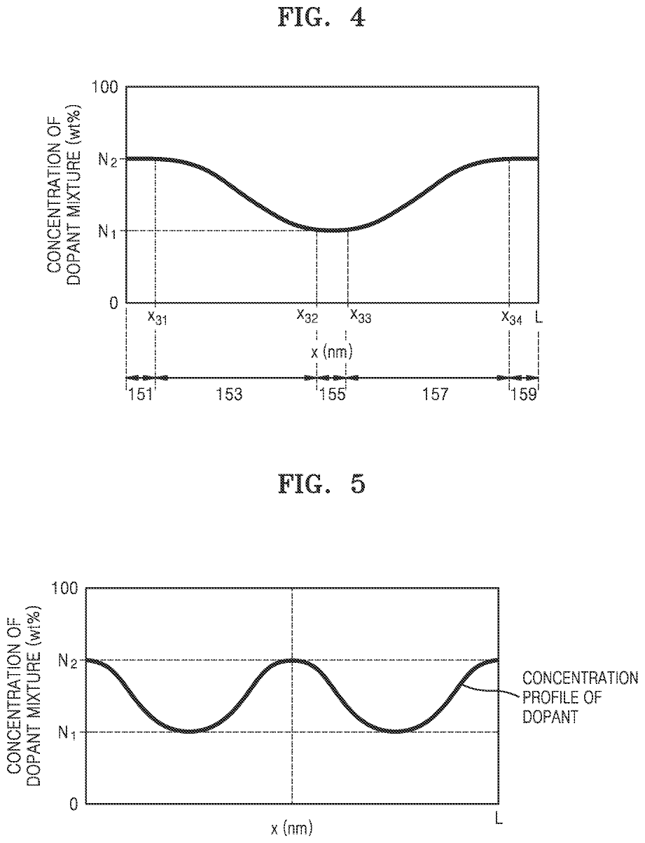

Next, a deposition source moving unit 350 on which the first deposition source 300 and the second deposition source 400 are arranged with a distance therebetween such that a deposition region C1 in which the vapor-state dopant composition 319 is present overlaps a deposition region C2 in which a vapor-state matrix material is present, the vapor-state matrix material being released from the second deposition source 400, is prepared. Here, an angle limiting plate 300A capable of defining each of the deposition region C1 in which the vapor-state dopant composition 319 is present and the deposition region C2 in which the vapor-state matrix material is present may be arranged at both sides of each of the first deposition source 300 and the second deposition source 400 (for convenience, illustration of the angle limiting plate 300A is omitted in FIGS. 2B to 2G). By adjusting the degree of overlap between the deposition region C1 in which the vapor-state dopant composition 319 is present and the deposition region C2 in which the vapor-state matrix material is present, the interval between the first deposition source 300 and the second deposition source 400, the arrangement order of the first deposition source 300 and the second deposition source 400, the amount of material released per hour from the first deposition source 300 and the second deposition source 400, the movement speed of the deposition source moving unit 350, the height and spacing of the angle limiting plate 300A, the number of reciprocations of the deposition source moving unit 350, the type of movement of the deposition source moving unit 350 (for example, one-way or reciprocal), or the like, the concentration profile of the dopant composition in the mixed layer 15 may be controlled (for example, see FIGS. 4 to 9).

Next, as shown in FIG. 2A, the deposition source moving unit 350 is arranged at a first end A below a surface of the substrate 12 such that the substrate 12 faces the deposition source moving unit 350. The deposition region C1 in which the vapor-state dopant composition 319 is present and the deposition region C2 in which the vapor-state matrix material is present may each have, as shown in FIG. 2A, a sectoral shape with a certain angle.

The first deposition source 300 and the second deposition source 400 may be arranged on the deposition source moving unit 350, and the deposition source moving unit 350 may be installed to reciprocate along a guide rail 340 arranged in a chamber. To this end, the deposition source moving unit 350 may be connected to a separate driving unit (not shown) to be driven.

As shown in FIG. 2A, in a state in which the first deposition source 300 and the second deposition source 400 are turned on or activated, the deposition source moving unit 350 on which the first deposition source 300 and the second deposition source 400 are arranged with a certain distance therebetween as described above may move in a direction B away from the first end A below the surface of the substrate 12 and toward a second end E. In this case, a region 151 in which the concentration of the dopant composition (that is, D_{con}(x)) is N₂ is mainly deposited on the surface of the substrate 12, so that the region 151 in which the concentration of the dopant composition is N₂ begins to form. The region 151 is formed to continuously extend as the deposition source moving unit 350 is moved in the direction B away from the first end A toward the second end E. As used herein, “N₁” indicates a minimum value of the dopant composition concentration in the mixed layer, and “N₂” indicates a maximum value of the dopant composition concentration in the mixed layer.

Then, as shown in FIG. 2B, when the deposition source moving unit 350 on which the first deposition source 300 and the second deposition source 400 are arranged continues to move in the direction B away from the first end A and toward the second end E, a region 153 (see “D2” in FIG. 2B) in which D_{con}(x) gradually decreases begins to form under the region 151. The region 153 is formed to continuously extend as the deposition source moving unit 350 is moved in the direction B away from the first end A and toward the second end E.

Next, as shown in FIG. 2C, when the deposition source moving unit 350 on which the first deposition source 300 and the second deposition source 400 are arranged continues to move in the direction B away from the first end A and toward the second end E, a region 155′ (see “D3” in FIG. 2C) in which D_{con}(x) is N₁ begins to form under the region 153.

Then, when the deposition source moving unit 350 on which the first deposition source 300 and the second deposition source 400 are arranged is moved in the direction B away from the first end A and toward the second end E, and arrives at the second end E below the substrate 12, as shown in FIG. 2D, the region 151 in which D_{con}(x) is N₂, the region 153 in which D_{con}(x) gradually decreases, and the region 155′ in which D_{con}(x) is N₁ may be sequentially formed on the surface of the substrate 12.

Immediately afterwards, as shown in FIG. 2E, the direction of movement of the deposition source moving unit 350 that has arrived at the second end E below the substrate 12 is changed into a direction F away from the second end E and toward the first end A, and the deposition source moving unit 350 is moved. In this case, as shown in FIG. 2E, a region 155″ in which D_{con}(x) is N₁ begins to form.

Next, when the deposition source moving unit 350 is moved in the direction F away from the second end E and toward the first end A, as shown in FIG. 2F, a region 157 in which D_{con}(x) gradually increases and a region 159 in which D_{con}(x) is N₂ may be sequentially formed. In this case, since a surface of the region 155′ and a surface of the region 155″ are in direct contact with each other, and the region 155′ and the region 155″ have substantially the same (e.g., have the same) components as each other and are formed in one chamber, an interface S′ between the region 155′ and the region 155″ may be substantially indistinct, and thus, the region 155′ and the region 155″ may be combined and represented as a region 155 in which D_{con}(x) is N₁.

Then, as the deposition source moving unit 350 including the first deposition source 300 and the second deposition source 400 arrives at the first end A below the surface of the substrate 12, as shown in FIG. 2G, the region 151 where D_{con}(x) is N₂, the region 153 where D_{con}(x) gradually decreases, the region 155 where D_{con}(x) is N₁, the region 157 where D_{con}(x) gradually increases, and the region 159 where D_{con}(x) is N₂ may be sequentially formed on the surface of the substrate 12.

As described with reference to FIGS. 2A to 2G, by performing, “one time”, a reciprocating process of moving the deposition source moving unit 350 in the direction B away from the first end A below the surface of the substrate 12 and toward the second end E, and then immediately moving the deposition source moving unit 350 in the direction F away from the second end E and toward the first end A, as shown in FIG. 4, the mixed layer 15 having a dopant composition concentration profile may be formed.

FIG. 4 is a diagram illustrating one or more embodiments of the concentration profile of the dopant composition showing the concentration of the dopant composition (y-axis) for each thickness of the mixed layer 15 (x-axis) that is formed by performing the above-described reciprocating process “one time”. L in FIG. 4 indicates a thickness of the mixed layer 15 as shown in FIG. 1, where x corresponds to a distance in nanometers (nm) extending from the first surface of the substrate. In FIG. 4, the regions indicated beneath the x-axis by 151, 153, 155, 157, and 159 correspond to those regions as labelled in FIGS. 2A to 2G. In FIG. 4, X₃₁, X₃₂, X₃₃, and X₃₄ may each be a real number satisfying 0<X₃₁<X₃₂<X₃₃<X₃₄<L, D_{con}(x) (that is, the concentration of the dopant composition) with respect to x satisfying 0≤x≤X₃₁ may be N₂, D_{con}(x) with respect to x satisfying X₃₁<x<X₃₂ may gradually decrease, D_{con}(x) with respect to x satisfying X₃₂<x X₃₃ may be N₁, D_{con}(x) with respect to x satisfying X₃₃<x<X₃₄ may gradually increase, and D_{con}(x) with respect to x satisfying X₃₄≤x≤L may be N₂. x, L, and D_{con}(x) are respectively the same as those described in the present specification, N₁ indicates a minimum value of the dopant composition concentration in the mixed layer 15, and N₂ indicates a maximum value of the dopant composition concentration in the mixed layer 15. For example, N₂ may be in a range of about 20 weight percent (wt %) to about 40 wt %, and N₁ may be in a range of about 1 wt % to about 5 wt %, based on a total weight of the mixed layer.

The mixed layer 15 may be formed, for example, by a deposition process in which the reciprocating process of the deposition source moving unit 350 described with reference to FIGS. 2A to 2G is performed one or more times.

For example, FIG. 5 is a diagram illustrating the dopant composition concentration profile in the mixed layer 15 that is formed by performing, “two consecutive times”, the reciprocating process of the deposition source moving unit 350 described with reference to FIGS. 2A to 2G. L in FIG. 5 indicates a thickness of the mixed layer 15 as shown in FIG. 1, where x corresponds to a distance in nanometers (nm) extending from the first surface of the substrate. It may be confirmed that the dopant composition concentration profile of FIG. 5 is obtained by extending the dopant composition concentration profile of FIG. 4 according to the thickness of the mixed layer 15.

As described above, the mixed layer 15 is a layer formed by deposition of the vapor-state matrix material and the vapor-state dopant composition 319. The vapor-state dopant composition 319 is a mixture of a vapor-state first dopant and a vapor-state second dopant. Thus, for example, as shown in FIGS. 4 and 5, the mixed layer 15 may have the concentration profile of the dopant composition (the composition or mixture of the first dopant and the second dopant) with respect to the thickness of the mixed layer 15.

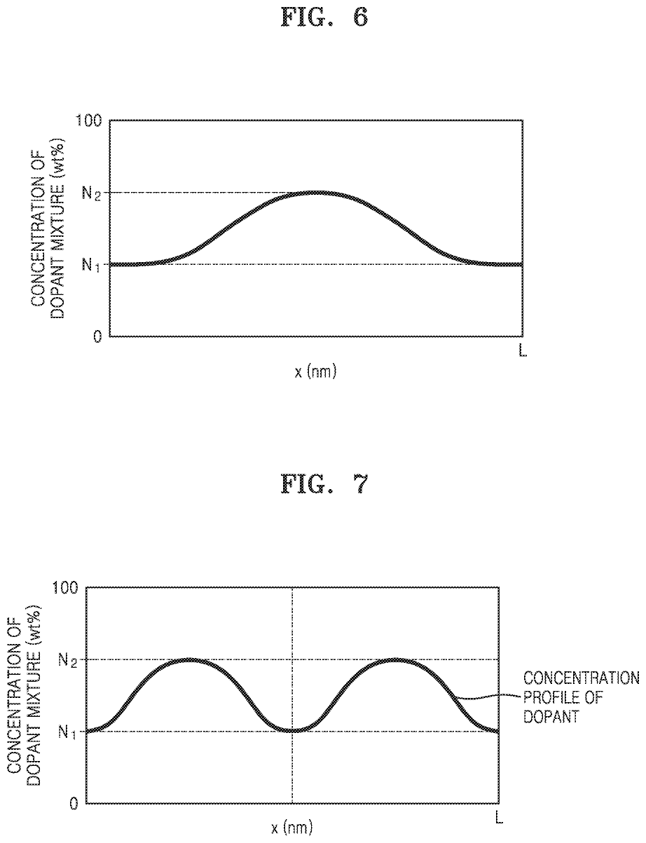

FIG. 6 is a diagram illustrating another embodiment of the concentration profile of the dopant composition showing the concentration of the dopant composition (y-axis) for each thickness of the mixed layer 15 (x-axis) and is a concentration profile showing that the concentration of the dopant composition gradually decreases and increases according to the thickness of the mixed layer 15. L in FIG. 6 indicates a thickness of the mixed layer 15 as shown in FIG. 1, where x corresponds to a distance in nanometers (nm) extending from the first surface of the substrate.

FIG. 7 is a diagram illustrating the dopant composition concentration profile in the mixed layer 15 that is formed by performing, “two consecutive times”, the reciprocating process of the deposition source moving unit 350 which may provide the concentration profile of the dopant composition of FIG. 6. L in FIG. 7 indicates a thickness of the mixed layer 15 as shown in FIG. 1, where x corresponds to a distance in nanometers (nm) extending from the first surface of the substrate. It may be confirmed that the dopant composition concentration profile of FIG. 7 is obtained by extending the dopant composition concentration profile of FIG. 6 according to the thickness of the mixed layer 15.

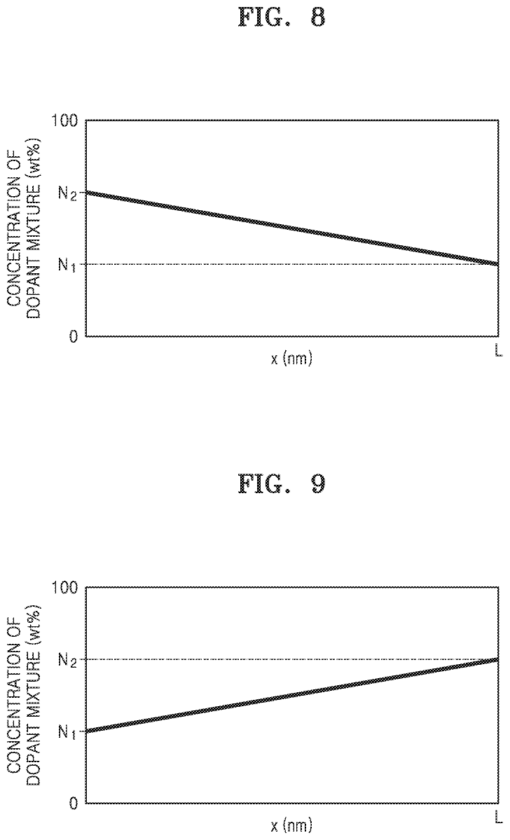

Meanwhile, the mixed layer 15 may be formed by one-way movement of the deposition source moving unit 350 as shown in FIGS. 2A to 2D, rather than the reciprocating movement of the deposition source moving unit 350 as shown in FIGS. 2A to 2G. As a result, for example, one or more embodiments of the concentration profile of the dopant composition as shown in FIGS. 8 and 9 may be realized.

FIG. 8 is a diagram illustrating another embodiment of the concentration profile of the dopant composition showing the concentration of the dopant composition (y-axis) for each thickness of the mixed layer 15 (x-axis), and is a concentration profile showing that the concentration of the dopant composition monotonically decreases according to the thickness of the mixed layer 15. L in FIG. 8 indicates a thickness of the mixed layer 15 as shown in FIG. 1, where x corresponds to a distance in nanometers (nm) extending from the first surface of the substrate. FIG. 9 is a diagram illustrating another embodiment of the concentration profile of the dopant composition showing the concentration of the dopant composition (y-axis) for each thickness of the mixed layer 15 (x-axis), and is a concentration profile showing that the concentration of the dopant composition monotonically increases according to the thickness of the mixed layer 15. L in FIG. 9 indicates a thickness of the mixed layer 15 as shown in FIG. 1, where x corresponds to a distance in nanometers (nm) extending from the first surface of the substrate.

The wording “concentration profile of the dopant composition” as used herein is a wording used for representing that a concentration profile of the first dopant with respect to the thickness of the mixed layer 15 and a concentration profile of the second dopant with respect to the thickness of the mixed layer 15 are substantially the same (e.g., are the same) at each thickness, and thus are not distinguished from each other based on the thickness of the mixed layer.

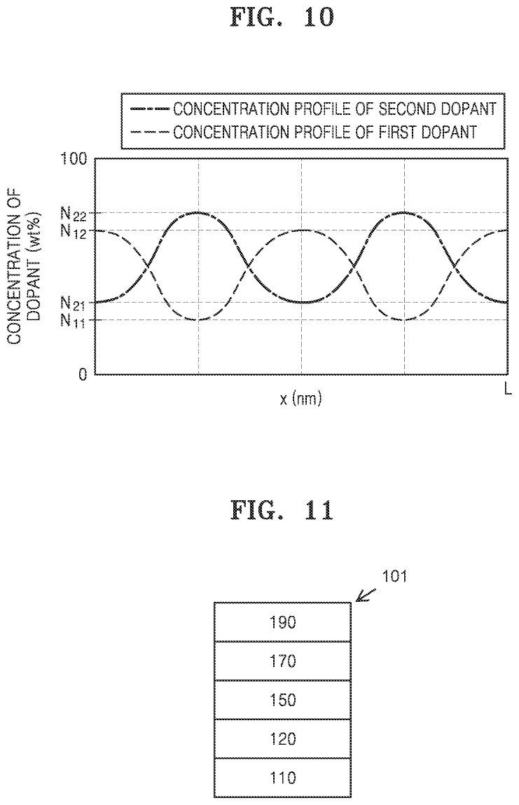

For comparison, FIG. 10 illustrates the concentration profiles of the first dopant and the second dopant with respect to a thickness of a layer B that is formed by using each of a deposition source B1 loaded with the first dopant and a deposition source B2 loaded with the second dopant, instead of the first deposition source 300 loaded with the first dopant and the second dopant, and by performing, “two consecutive times”, the reciprocating process of the deposition source moving unit 350 described with reference to FIGS. 2A to 2G. In FIG. 10, x and L are respectively the same as those described in the present specification, N₁₁ indicates a minimum value of the first dopant concentration in the layer B, N₁₂ indicates a maximum value of the first dopant concentration in the layer B, N₂₁ indicates a minimum value of the second dopant concentration in the layer B, and N₂₂ indicates a maximum value of the second dopant concentration in the layer B.

In FIG. 10, which shows the comparative process, since each of the deposition source B1 and the deposition source B2 are used, the layer B has each of a concentration profile of the first dopant with respect to the thickness of the layer B and a concentration profile of the second dopant with respect to the thickness of the layer B, and the two concentration profiles are clearly distinguished from each other. Accordingly, the layer B does not have the “concentration profile of the dopant composition” as defined in the present specification because the concentration of the first dopant with respect to the thickness of the mixed layer and the concentration of the second dopant with respect to the thickness of the mixed layer are not substantially the same, or are not the same. In the layer B, the concentrations of the first dopant and the second dopant may be different at a specific thickness x (nm), and thus, effects that may be obtained by doping the first dopant and the second dopant in the matrix material at substantially the same time (e.g., at the same time) may not be fully realized, or may not be substantially realized.

However, in the mixed layer 15, the concentrations of the first dopant and the second dopant may be substantially the same (e.g., the same) in all thickness x (nm) ranges satisfying 0≤x≤L, and thus, the effects that may be obtained by doping the first dopant and the second dopant in the matrix material at substantially the same time (e.g. at the same time) may be fully realized.

Meanwhile, the mixed layer 15 satisfies the relationship where Tₘ₁>Tₚ>Tₘ₁₊₂.

Here, Tₘ₁ is a melting point of the first dopant,
Tₚ is a deposition temperature used in forming the mixed layer 15, and
Tₘ₁₊₂ is:
a melting point of a pre-mixed composition of the first dopant and the second dopant, wherein the pre-mixed composition is crystalline, and
a fusion temperature of a pre-mixed composition of the first dopant and the second dopant, wherein the pre-mixed composition is amorphous. As used herein, “fusion temperature” refers to a temperature wherein a volume of the pre-mixed composition changes.

In the present specification, a melting point and a fusion temperature may be evaluated according to a known method. For example, the melting point and the fusion temperature may be evaluated by performing differential scanning calorimeter (DSC) analysis on the pre-mixed composition, or using a melting point apparatus.

In addition, a deposition temperature of the depositing process in the formation of the mixed layer 15 illustrated in FIGS. 2A to 2G may be lower than a melting point of the first dopant, and i) when a pre-mixed composition of the first dopant and the second dopant is crystalline, the deposition temperature of the depositing process may be greater than a melting point of the pre-mixed composition, and, ii) when the pre-mixed composition of the first dopant and the second dopant is amorphous, the deposition temperature of the depositing process may be greater than a fusion temperature of the pre-mixed composition.

When the first dopant including the transition metal is sublimed after melting, thermal denaturation such as separation of the transition metal and the ligand included in the first dopant may occur. However, since the mixed layer 15 satisfies Tₘ₁>Tₚ, the first dopant including the transition metal is sublimated before melting and used for deposition, and thus, the first dopant may be doped in the mixed layer 15 without thermal denaturation.

In addition, as illustrated in FIG. 3, the tray 301 includes the first region 311R including only the first dopant 311 and the second region 312R including only the second dopant 312, respectively, and is formed by using the first deposition source 300 in which the first dopant 311 and the second dopant 312 are not pre-mixed with each other, and thus, the condition of Tₚ>Tₘ₁₊₂ may be selected. Accordingly, the mixed layer 15 may be formed at a relatively high deposition temperature, and thus, process stability may be significantly improved when the mixed layer 15 is manufactured. Also, since deposition may be performed quickly at a relatively high deposition temperature, it is possible to increase productivity by reducing a tact time, thereby reducing manufacturing costs.

In the case where, to solve the issue that the concentration profile of the first dopant and the concentration profile of the second dopant separately exist (see FIG. 10 and the description of FIG. 10 above), a layer A is formed by using a deposition source A including the pre-mixed composition of the first dopant and the second dopant, instead of the first deposition source 300 that includes both the first region 311R including only the first dopant 311 and the second region 312R including only the second dopant 312 such that the first dopant 311 and the second dopant 312 are not mixed with each other, it is necessary to select the condition of Tₘ₁₊₂>Tₚ. As described above, when the first dopant including a transition metal is sublimed after melting, thermal denaturation such as separation of the transition metal and the ligand included in the first dopant may occur. Thus, to prevent thermal denaturation of the first dopant during deposition, it is necessary to select the condition of Tₘ₁₊₂>Tₚ when the layer A is deposited using the deposition source A (see the device characteristics of the light-emitting devices including the layer A deposited under the condition of Tₚ>Tₘ₁₊₂ in Evaluation Examples described below). Here, the pre-mixed composition of the first dopant and the second dopant i) may be changed into an amorphous state during pre-mixing, or ii) may have a melting point (Tₘ₁₊₂) that is significantly lower than the melting point (Tₘ₁) of the first dopant and the melting point (Tₘ₂) of the second dopant. Accordingly, when the deposition source A is used, it is necessary to select a relatively low deposition temperature (Tₚ). However, when a deposition process is performed at a relatively low deposition temperature, the tact time may be lengthened, and thus, the process stability may be impaired, and the manufacturing costs may increase.

To summarize the above,
1) since the mixed layer 15 has a concentration profile of a dopant composition (a mixture of a first dopant and a second dopant) with respect to a thickness of the mixed layer 15, non-uniformity between a concentration of the first dopant and a concentration of the second dopant for each thickness of the mixed layer 15 may be prevented, and thus, effects that may be obtained by doping the first dopant and the second dopant in a matrix material at substantially the same time (e.g., at the same time) may be fully realized, and
2) since the mixed layer 15 satisfies the condition of Tₘ₁>Tₚ>Tₘ₁₊₂ as described above, in a deposition process for forming the mixed layer 15, i) thermal denaturation of the first dopant including a transition metal may be prevented, and thus, the mixed layer 15 having higher quality may be manufactured, and ii) a tact time for forming the mixed layer 15 may be relatively short, and thus, process stability may be improved, and manufacturing costs may be reduced.

In one or more embodiments, the second dopant in the mixed layer 15 may include a transition metal (for example, one transition metal).

For example, the second dopant may be an organometallic compound including a transition metal and at least one ligand bonded to the transition metal.

The second dopant may be neutral or have net neutral charge.

In one or more embodiments, the second dopant may include iridium or platinum.

In one or more embodiments, the second dopant may include a transition metal, and the mixed layer may satisfy Tₘ₂>Tₚ. Here, Tₚ is the same as described in the present specification, and Tₘ₂ indicates the melting point of the second dopant. Accordingly, since the second dopant including the transition metal is sublimated before melting and used for deposition, the second dopant may be doped in the mixed layer 15 without thermal denaturation.

In one or more embodiments, the second dopant may not include a transition metal. For example, the second dopant may be a fluorescent material. In one or more embodiments, the second dopant may be a compound including a cyclic group including a boron atom and a nitrogen atom as ring forming atoms.

In one or more embodiments, the mixed layer 15 may be an emission layer, and depending on the highest occupied molecular orbital (HOMO) energy level, the lowest unoccupied molecular orbital (LUMO) energy level, the triplet (T₁) energy level, the singlet (S₁) energy level, and the like between the matrix material, the first dopant, and the second dopant included in the mixed layer 15,
each of the first dopant and the second dopant may be an emitter,
the first dopant may be an emitter, and the second dopant may be a sensitizer; or
the first dopant may be a sensitizer, and the second dopant may be an emitter.

In one or more embodiments, the mixed layer 15 may be an emission layer, and
each of the first dopant and the second dopant may emit red light;
each of the first dopant and the second dopant may emit green light; or
each of the first dopant and the second dopant may emit blue light.

The mixed layer 15 may be used in various electronic devices, for example, light-emitting devices (for example, organic light-emitting devices). Thus, according to another aspect, provided is a light-emitting device including a first electrode, a second electrode facing the first electrode, and an interlayer arranged between the first electrode and the second electrode, wherein the interlayer includes the mixed layer 15.

In one or more embodiments, the interlayer may include an emission layer, and the emission layer may be the mixed layer 15.

In one or more embodiments, the interlayer may include a hole transport region arranged between the first electrode and the emission layer and an electron transport region arranged between the emission layer and the second electrode.

Meanwhile, the interlayer may include:
m light-emitting units that include at least one emission layer; and
m−1 charge generation layers that are arranged between two neighboring light-emitting units of the m light-emitting units,
wherein m may be an integer of 2 or more. For example, m may be 2, 3, 4, 5, 6, 7, 8, 9, or 10. In one or more embodiments, m may be 2, 3, 4, 5, 6, or 7.

That is, the light-emitting device may be a tandem light-emitting device.

In one or more embodiments, at least one light-emitting unit of the light-emitting units in the number of m may include the mixed layer 15 as described herein. For example, the mixed layer 15 included in the light-emitting unit may be an emission layer.

In one or more embodiments, at least one light-emitting unit of the light-emitting units in the number of m may emit green light.

In one or more embodiments, at least one light-emitting unit of the light-emitting units in the number of m may include the mixed layer 15 as described herein, the mixed layer 15 may be an emission layer, and the emission layer may emit green light.

In one or more embodiments, at least one light-emitting unit of the light-emitting units in the number of m may include the mixed layer 15 as described herein, and the light-emitting unit including the mixed layer 15 may emit green light.

In one or more embodiments, at least one light-emitting unit of the light-emitting units in the number of m may emit green light, and at least one light-emitting unit of the remaining light-emitting units may emit blue light.

According to another aspect, the light-emitting device may be included in an electronic apparatus. Thus, an electronic apparatus including the light-emitting device is provided. The electronic apparatus may include, for example, a display, an illumination, a sensor, and the like.

### Description of First Dopant and Second Dopant

Hereinafter, a first dopant and a second dopant will be described in detail.

The first dopant may be a first compound, and the second dopant may be a second compound. Accordingly, the term “composition of the first compound and the second compound” as used herein refers to a “composition of the first dopant and the second dopant”.

The first compound may emit first light having a first spectrum and λP(1) is the emission peak wavelength (nm) in the first spectrum, and the second compound may emit second light having a second spectrum and λP(2) is the emission peak wavelength (nm) in the second spectrum, wherein the absolute value of the difference between λP(1) and λP(2) may be in a range of about 0 nm to about 30 nm, about 0 nm to about 25 nm, about 0 nm to about 20 nm, about 0 nm to about 15 nm, or about 0 nm to about 10 nm, and λP(1) and λP(2) may each be in a range of about 500 nm to about 570 nm or about 500 nm to about 550 nm. In one or more embodiments, λP(1) and λP(2) may each be in a range of about 500 nm to about 540 nm or about 510 nm to about 540 nm.

λP(1) and λP(2) may be evaluated from the photoluminescence (PL) spectra measured with respect to a first film and a second film, respectively.

The term “first film” as used herein refers to a film including the first compound, and the term “second film” as used herein refers to a film including the second compound. The first film and the second film may be manufactured using various methods, such as a vacuum deposition method, a coating method, and a heating method. The first film and the second film may further include a compound, for example, a host described herein, other than the first compound and the second compound.

In one or more embodiments, the first compound and the second compound may each independently be an emitter.

In one or more embodiments, the first compound and the second compound may each be an emitter, and λP(1) and λP(2) may each be in a range of about 510 nm to about 540 nm.

In one or more embodiments, the first compound may be an emitter, and the second compound may be a sensitizer.

In one or more embodiments, the first compound may be a sensitizer, and the second compound may be an emitter.

In one or more embodiments, the first compound may be a sensitizer, the second compound may be an emitter, λP(1) may be in a range of about 500 nm to about 520 nm, and λP(2) may be in a range of about 510 nm to about 540 nm.

In one or more embodiments, the first compound and the second compound may each independently be a phosphorescent compound.

The phosphorescent compound may be an organometallic compound including a transition metal (for example, iridium, platinum, osmium, or the like), and may be electrically neutral.

For example, the phosphorescent compound may be a platinum-containing organometallic compound or an iridium-containing organometallic compound. In one or more embodiments, the platinum-containing organometallic compound may be a platinum-containing organometallic compound including platinum and a tetradentate ligand bonded to the platinum. For example, the tetradentate ligand may include carbon and oxygen (or, sulfur), and the platinum-containing organometallic compound may include a) a chemical bond between the carbon of the tetradentate ligand and the platinum and b) a chemical bond between the oxygen (or, sulfur) of the tetradentate ligand and the platinum.

In one or more embodiments, the first compound may be a phosphorescent compound, and the second compound may be a fluorescent compound.

The fluorescent compound may be a thermally activated delayed fluorescence compound or a prompt fluorescent compound.

The first compound and the second compound may each independently satisfy Condition 1 or Condition 2:
Condition 1
The first compound is a platinum-containing organometallic compound including platinum and a tetradentate ligand bonded to the platinum, and
the second compound is an iridium-containing organometallic compound.
Condition 2
Each of the first compound and the second compound is an iridium-containing organometallic compound.

In one or more embodiments, the first compound and the second compound may satisfy Condition 1,
μ(Pt) may be in a range of about 0.5 debye to about 5.0 debye,
μ(Pt) may be smaller than μ(Ir),
wherein μ(Pt) is a dipole moment of the first compound,
wherein μ(Ir) is a dipole moment of the second compound, and
each of μ(Pt) and μ(Ir) may be calculated based on density functional (DFT) theory.
   Any various programs may be used for the quantum mechanical calculation based on the DFT, and for example, a Gaussian 16 program may be used.

In the case of a composition of the first compound and the second compound that satisfy Condition 1, aggregation among molecules of the first compound in the composition, aggregation among molecules of the second compound in the composition, and/or aggregation among molecules of the first compound and molecules of the second compound in the composition may be substantially minimized. Accordingly, without any consideration about intermolecular aggregation, the amounts (for example, weight) of the first compound and the second compound in the composition may be relatively increased. Accordingly, the mixed layer 15 including the composition and a light-emitting device including the composition may have excellent luminescence efficiency and lifespan characteristics. In addition, when an light-emitting unit of a light-emitting device includes the composition of the first compound and the second compound that satisfy Condition 1, the hole flux in the light-emitting unit may be increased due to the composition, so that an exciton recombination zone in the light-emitting unit may be spaced apart from each of the interface between an emission layer and a hole transport region and the interface between an emission layer and an electron transport region, resulting in improved lifespan characteristics of the light-emitting device.

The platinum-containing organometallic compound may include one platinum atom and may not include metals other than platinum.

The platinum-containing organometallic compound may not include ligands other than the tetradentate ligand bonded to the platinum.

The tetradentate ligand bonded to the platinum in the platinum-containing organometallic compound may have excellent electrical characteristics and structural rigidity. In addition, the platinum-containing organometallic compound having the tetradentate ligand bonded to the platinum has a planar structure, and thus may have a relatively small dipole moment.

The iridium-containing organometallic compound may include one iridium atom, may not include metals other than iridium.

The terms “dipole moment of the first compound” and “dipole moment of the second compound” as used herein may refer to “total permanent dipole moment in the molecule of the first compound” and “total permanent dipole moment in the molecule of the second compound”, respectively.

In one or more embodiments, μ(Pt) may be in a range of about 1.5 debye to about 5.0 debye.

In one or more embodiments, μ(Pt) may be in a range of about 0.5 debye to about 3.0 debye, about 1.0 debye to about 3.0 debye, about 1.5 debye to about 3.0 debye, about 1.7 debye to about 3.0 debye, or about 1.7 debye to about 2.7 debye.

In one or more embodiments, μ(Pt) may be in a range of about 2.0 debye to about 5.0 debye, about 3.0 debye to about 5.0 debye, or about 4.0 debye to about 5.0 debye.

In one or more embodiments, μ(Ir) may be in a range of about 4.0 debye to about 9.0 debye, about 4.5 debye to about 7.5 debye, or about 5.0 debye to about 7.0 debye.

In one or more embodiments, μ(Ir)−μ(Pt) may be in a range of about 0.3 debye to about 4.0 debye.

In one or more embodiments, μ(Ir)−μ(Pt) may be in a range of about 2.0 debye to about 4.0 debye or about 2.0 debye to about 3.0 debye.

In one or more embodiments, μ(Ir)−μ(Pt) may be in a range of about 0.3 debye to about 1.0 debye.

In one or more embodiments, in Condition 1,
λP(Pt) may be equal to λP(Ir),
λP(Pt) may be less than λP(Ir),
λP(Pt) may be greater than λP(Ir), or
λP(Pt) and λP(Ir) may each be in a range of about 510 nm to about 570 nm,
λP(Pt) and λP(Ir) may each be in a range of about 510 nm to about 540 nm,
λP(Pt) may be in a range of about 510 nm to about 530 nm, and λP(Ir) may be in a range of about 520 nm to about 540 nm,
λP(Pt) and λP(Ir) may each be in a range of about 540 nm to about 570 nm, or
vλP(Pt) may be in a range of about 540 nm to about 560 nm, and
λP(Ir) may be in a range of about 550 nm to about 570 nm.

In one or more embodiments, the composition of the first compound and the second compound may satisfy Condition 2, and at least one of Equation 1 to Equation 4. Accordingly, a light-emitting device including the mixed layer 15 including the composition of the first compound and the second compound that satisfies Condition 2 may have better luminescence efficiency and long lifespan:

λP(Ir1)>λP(Ir2) Equation 1

PLQY(Ir1)>PLYQ(Ir2) Equation 2

kᵣ(Ir1)>kᵣ(Ir2) Equation 3

HOR(Ir1)>HOR(Ir2) Equation 4

wherein, in Equations 1 to 4,
in relation to Equation 1, λP(Ir1) is the emission peak wavelength of the first compound, and λP(Ir2) is the emission peak wavelength of the second compound.
λP(Ir1) and λP(Ir2) may be evaluated from the PL spectra measured with respect to the first film and the second film, respectively.

In relation to Equation 2, PLQY(Ir1) is the PL quantum yield of the first compound, and PLQY(Ir2) is the PL quantum yield of the second compound.

PLQY(Ir1) and PLYQ(Ir2) may be measured with respect to the first film and the second film, respectively.

In relation to Equation 3, kᵣ(Ir1) is the radiative decay rate of the first compound, and kᵣ(Ir2) is the radiative decay rate of the second compound.

kᵣ(Ir1) and kᵣ(Ir2) may be evaluated from PL spectra and time-resolved PL spectra measured with respect to the first film and the second film, respectively.

In relation to Equation 4, HOR(Ir1) is the horizontal orientation ratio of the first compound, and HOR(Ir2) is the horizontal orientation ratio of the second compound.

HOR(Ir1) and HOR(Ir2) may be respectively evaluated from the emission intensity of the first film and the second film with respect to angle.

The first film and the second film are respectively the same as those described in the present specification.

In one or more embodiments, the composition of the first compound and the second compound that satisfies Condition 2 may satisfy
Equation 1,
at least one of Equation 2 to Equation 4, or
Equation 1, and at least one of Equation 2 to Equation 4.

In one or more embodiments, the composition of the first compound and the second compound that satisfies Condition 2 may further satisfy Equation 5:

HOMO(Ir1)<HOMO(Ir2) Equation 5
wherein, in Equation 5,
HOMO(Ir1) is the HOMO energy level of the first compound,
HOMO(Ir2) is the HOMO energy level of the second compound, and
each of HOMO(Ir1) and HOMO(Ir2) is a negative value measured using an atmospheric photoelectron spectrometer.

Each of HOMO(Ir1) and HOMO(Ir2) may be a negative value measured using an atmospheric photoelectron spectrometer, for example, AC3 manufactured by RIKEN KEIKI Co., Ltd.

Since the composition of the first compound and the second compound satisfying Condition 2 satisfies Equation 5, the second compound in the composition has a shallower HOMO energy level than the first compound, and a relatively greater amount of holes may be trapped in the second compound. As a result, in a light-emitting device including the mixed layer 15 including the composition of the first compound and the second compound, without the phenomenon in which the first compound and the second compound are changed into an anionic state due to electrons injected into the composition and the increase in the driving voltage, holes and electrons may effectively recombine in the first compound and/or the second compound. Accordingly, the light-emitting device may have excellent luminescence efficiency characteristics and excellent lifespan characteristics.

In one or more embodiments, regarding the composition of the first compound and the second compound satisfying Condition 2,
   |HOMO(Ir1)−HOMO(Ir2)| may be in a range of about 0.03 eV to about 0.30 eV,
HOMO(Ir1) may be the HOMO energy level of the first compound,
HOMO(Ir2) may be the HOMO energy level of the second compound,
   |HOMO(Ir1)−HOMO(Ir2)| may be the absolute value of HOMO(Ir1)−HOMO(Ir2), and
each of HOMO(Ir1) and HOMO(Ir2) may be a negative value measured using an atmospheric photoelectron spectrometer.

In one or more embodiments, the platinum-containing organometallic compound in Condition 1 may be an organometallic compound comprising a) a chemical bond between the carbon of the tetradentate ligand and the platinum and b) a chemical bond between the oxygen of the tetradentate ligand and the platinum.

In one or more embodiments, each of the iridium-containing organometallic compounds in Condition 1 and Condition 2 may include a first ligand, a second ligand, and a third ligand,
a) the first ligand, the second ligand, and the third ligand may be identical to each other, b) the first ligand and the second ligand may be identical to each other, and the second ligand and the third ligand may be different from each other, or c) the first ligand, the second ligand, and the third ligand may be different from each other, and
the first ligand, the second ligand, and the third ligand may each be:
a bidentate ligand bonded to the iridium of the iridium-containing organometallic compound via two nitrogen atoms;
a bidentate ligand bonded to the iridium of the iridium-containing organometallic compound via nitrogen and carbon; or
a bidentate ligand bonded to the iridium of the iridium-containing organometallic compound via two carbons.

In one or more embodiments, the platinum-containing organometallic compound may be an organometallic compound represented by Formula 1, and the iridium-containing organometallic compound may be an organometallic compound represented by Formula 2:

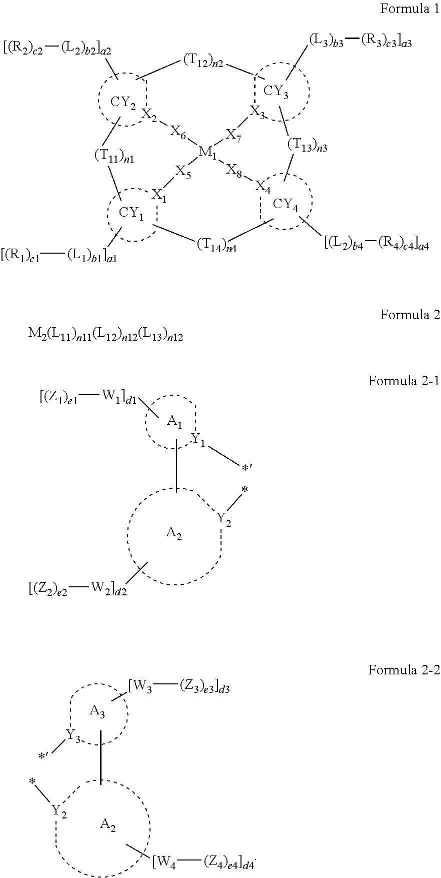

wherein,
M₁ in Formula 1 may be platinum (Pt), palladium (Pd), or gold (Au),
M₂ in Formula 2 may be iridium (Ir),
L₁₁ in Formula 2 may be a ligand represented by Formula 2-1,
L₁₂ in Formula 2 may be a ligand represented by Formula 2-2,
L₁₃ in Formula 2 may be a ligand represented by Formula 2-1 or 2-2,
L₁₁ and L₁₂ in Formula 2 may be different from each other,
n11, n12, and n13 in Formula 2 may each independently be 0, 1, 2, or 3, and the sum of n11, n12, and n13 may be 3,
X₁ to X₄ and Y₁ to Y₄ in Formulae 1, 2-1, and 2-2 may each independently be C or N,
X₅ to X₈ in Formula 1 may each independently be a chemical bond, O, S, N(R′), C(R′)(R″), or C(═O), and at least one of X₅ to X₈ may not be a chemical bond,
in Formula 1, two of a bond between X₅ or X₁ and M₁, a bond between X₆ or X₂ and M₁, a bond between X₇ or X₃ and M₁, and a bond between X₈ or X₄ and M₁ may each be a coordinate bond, and the other two may each be a covalent bond,
ring CY₁ to ring CY₄ and ring A₁ to ring A₄ in Formulae 1, 2-1, and 2-2 may each independently be a C₅-C₃₀ carbocyclic group or a C₁-C₃₀ heterocyclic group,
T₁₁ to T₁₄ in Formula 1 may each independently be a single bond, a double bond, *—N(R₅ₐ)—*′, *—B(R₅ₐ)—*′, *—P(R₅ₐ)—*′, *—C(R₅ₐ)(R_{5b})—*′, *—Si(R₅ₐ)(R_{5b})—*′, *—Ge(R₅ₐ)(R_{5b})—*′, *—S—*′, *—Se—*′, *—O—*′, *—C(═O)—*′, *—S(═O)—*′, *—S(═O)₂—*, *—C(R₅ₐ)═*′, *═C(R₅ₐ)—*′, *—C(R₅ₐ)═C(R_{5b})—*, *—C(═S)—*′, *—C≡C—*′, a C₅-C₃₀ carbocyclic group unsubstituted or substituted with at least one R₁₀ₐ, or a C₁-C₃₀ heterocyclic group unsubstituted or substituted with at least one R₁₀ₐ,
n1 to n4 in Formula 1 may each independently be 0 or 1, and 3 or more of n1 to n4 may each be 1,
in Formula 1, when n1 is 0, T₁₁ may not exist, when n2 is 0, T₁₂ may not exist, when n3 is 0, T₁₃ may not exist, and when n4 is 0, T₁₄ may not exist,
L₁ to L₄ and W₁ to W₄ in Formulae 1, 2-1, and 2-2 may each independently be a single bond, a C₁-C₂₀ alkylene group unsubstituted or substituted with at least one R₁₀ₐ, a C₅-C₃₀ carbocyclic group unsubstituted or substituted with at least one R₁₀ₐ, or a C₁-C₃₀ heterocyclic group unsubstituted or substituted with at least one R₁₀ₐ,
b1 to b4 in Formula 1 may each independently be an integer from 1 to 10,
R₁ to R₄, R₅ₐ, R_{5b}, R′, R″, and Z₁ to Z₄ in Formulae 1, 2-1, and 2-2 may each independently be hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉),
c1 to c4, a1 to a4, e1 to e4, and d1 to d4 in Formulae 1, 2-1, and 2-2 may each independently be an integer from 0 to 20,
the second compound may not be tris[2-phenylpyridine]iridium,
in Formulae 1, 2-1, and 2-2, at least one of i) two or more of a plurality of R₁(s), ii) two or more of a plurality of R₂(s), iii) two or more of a plurality of R₃(s), iv) two or more of a plurality of R₄(s), v) R₅ₐ and R_{5b}, vi) two or more of a plurality of Z₁(s), vii) two or more of a plurality of Z₂(s), viii) two or more of a plurality of Z₃(s), ix) two or more of a plurality of Z₄(s), x) two or more of R₁ to R₄, R₅ₐ, and R_{5b}, and xi) two or more of Z₁ to Z₄ may optionally be bonded to each other to form a C₅-C₃₀ carbocyclic group unsubstituted or substituted with at least one R₁₀ₐ or a C₁-C₃₀ heterocyclic group unsubstituted or substituted with at least one R₁₀ₐ,
R₁₀ₐ is as described in connection with R₁,
* and *′ each indicate a binding site to M₂,
at least one substituent of the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ aryl alkyl group, the substituted C₇-C₆₀ alkyl aryl group, the substituted C₆-C₆₀ aryloxy group, the substituted C₆-C₆₀ arylthio group, the substituted C₁-C₆₀ heteroaryl group, the substituted C₂-C₆₀ alkyl heteroaryl group, the substituted C₂-C₆₀ heteroaryl alkyl group, the substituted C₁-C₆₀ heteroaryloxy group, the substituted C₁-C₆₀ heteroarylthio group, the substituted monovalent non-aromatic condensed polycyclic group, and the substituted monovalent non-aromatic condensed heteropolycyclic group may be:
deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, or C₁-C₆₀ alkoxy group, or a C₁-C₆₀ alkylthio group;
a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, each substituted with at least one of deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or a combination thereof;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, or a monovalent non-aromatic condensed heteropolycyclic group, each unsubstituted or substituted with at least one of deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or a combination thereof;
—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉); or
a combination thereof, and
Q₁ to Q₉, Q₁₁ to Q₁₉, Q₂₁ to Q₂₉, and Q₃₁ to Q₃₉ may each independently be: hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₇-C₆₀ aryl alkyl group, a C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, or a monovalent non-aromatic condensed heteropolycyclic group, each unsubstituted or substituted with deuterium, a C₁-C₆₀ alkyl group, a C₆-C₆₀ aryl group, or a combination thereof.

In Formula 2, n11 to n13 indicate the number of L₁₁(s) to the number of L₁₃(s), respectively, and may each independently be 0, 1, 2, or 3, wherein a sum of n11, n12, and n13 may be 3.

For example, in Formula 2, n11 may be 1, 2, or 3, and n12 and n13 may each independently be 0, 1, or 2.

In one or more embodiments, in Formula 2, n12 may be 1, 2, or 3, and n11 and n13 may each independently be 0, 1, or 2.

In one or more embodiments, n11 may be 1, n12 may be 2, and n13 may be 0.

In one or more embodiments, n11 may be 2, n12 may be 1, and n13 may be 0.

In one or more embodiments, n11 may be 3, and n12 and n13 may each be 0.

In one or more embodiments, n12 may be 3, and n11 and n13 may each be 0.

The iridium-containing organometallic compound represented by Formula 2 may be a heteroleptic complex or a homoleptic complex.

For example, the iridium-containing organometallic compound may be a heteroleptic complex.

X₁ to X₄ and Y₁ to Y₄ in Formulae 1, 2-1, and 2-2 may each independently be C or N.

For example, at least one of X₁ to X₄ in Formula 1 may be C.

In one or more embodiments, X₁ in Formula 1 may be C.

In one or more embodiments, in Formula 1, i) X₁ and X₃ may each be C, and X₂ and X₄ may each be N, or ii) X₁ and X₄ may each be C, and X₂ and X₃ may each be N.

In one or more embodiments, in Formulae 2-1 and 2-2, Y₁ and Y₃ may each be N, and Y₂ and Y₄ may each be C.

In Formula 1, X₅ to X₈ may each independently be a chemical bond, O, S, N(R′), C(R′)(R″), or C(═O), and at least one of X₅ to X₈ may not be a chemical bond. R′ and R″ are respectively the same as those described in the present specification.

In one or more embodiments, X₅ in Formula 1 may not be a chemical bond.

In one or more embodiments, X₅ in Formula 1 may be O or S.

In one or more embodiments, in Formula 1, X₅ may be O or S, and X₆ to X₈ may each be a chemical bond.

In Formula 1, two of a bond between X₅ or X₁ and M₁, a bond between X₆ or X₂ and M₁, a bond between X₇ or X₃ and M₁, and a bond between X₈ or X₄ and M₁ may each be a coordinate bond, and the other two may each be a covalent bond.

For example, a bond between X₂ and M in Formula 1 may be a coordinate bond.

In one or more embodiments, in Formula 1, a bond between X₅ or X₁ and M and a bond between X₃ and M may each be a covalent bond, and a bond between X₂ and M and a bond between X₄ and M may each be a coordinate bond.

In one or more embodiments, the platinum-containing organometallic compound and the iridium-containing organometallic compound may each be electrically neutral.

Ring CY₁ to ring CY₄ and ring A₁ to ring A₄ in Formulae 1, 2-1, and 2-2 may each independently be a C₅-C₃₀ carbocyclic group or a C₁-C₃₀ heterocyclic group.

For example, each of ring CY₁, ring CY₃, and ring CY₄ may not be a benzimidazole group.

For example, ring CY₁ to ring CY₄ and ring A₁ to ring A₄ in Formulae 1, 2-1, and 2-2 may each independently be i) a first ring, ii) a second ring, iii) a condensed ring in which two or more first rings are condensed with each other, iv) a condensed ring in which two or more second rings are condensed with each other, or v) a condensed ring in which at least one first ring and at least one second ring are condensed with each other,
the first ring may be a cyclopentane group, a cyclopentene group, a furan group, a thiophene group, a pyrrole group, a silole group, a borole group, a phosphole group, a germole group, a selenophene group, an oxazole group, an oxadiazole group, an oxatriazole group, a thiazole group, a thiadiazole group, a thiatriazole group, a pyrazole group, an imidazole group, a triazole group, a tetrazole group, or an azasilole group, and
the second ring may be an adamantane group, a norbornane group, a norbornene group, a piperidine group, a cyclohexane group, a cyclohexene group, a benzene group, a pyridine group, a pyrimidine group, a pyrazine group, a pyridazine group, or a triazine group.

In one or more embodiments, ring CY₁ to ring CY₄ and ring A₁ to ring A₄ in Formulae 1, 2-1, and 2-2 may each independently be a cyclopentane group, a cyclohexane group, a cyclohexene group, a benzene group, a naphthalene group, an anthracene group, a phenanthrene group, a triphenylene group, a pyrene group, a chrysene group, a 1,2,3,4-tetrahydronaphthalene group, a cyclopentadiene group, a pyrrole group, a furan group, a thiophene group, a silole group, a borole group, a phosphole group, a germole group, a selenophene group, an indene group, an indole group, a benzofuran group, a benzothiophene group, a benzosilole group, a benzoborole group, a benzophosphole group, a benzogermole group, a benzoselenophene group, a fluorene group, a carbazole group, a dibenzofuran group, a dibenzothiophene group, a dibenzosilole group, a dibenzoborole group, a dibenzophosphole group, a dibenzogermole group, a dibenzoselenophene group, a benzofluorene group, a benzocarbazole group, a naphthobenzofuran group, a naphthobenzothiophene group, a naphthobenzosilole group, a naphthobenzoborole group, a naphthobenzophosphole group, a naphthobenzogermole group, a naphthobenzoselenophene group, a dibenzofluorene group, a dibenzocarbazole group, a dinaphthofuran group, a dinaphthothiophene group, a dinaphthosilole group, a dinaphthoborole group, a dinaphthophosphole group, a dinaphthogermole group, a dinaphthoselenophene group, an indenophenanthrene group, an indolophenanthrene group, a phenanthrobenzofuran group, a phenanthrobenzothiophene group, a phenanthrobenzosilole group, a phenanthrobenzoborole group, a phenanthrobenzophosphole group, a phenanthrobenzogermole group, a phenanthrobenzoselenophene group, a dibenzothiophene 5-oxide group, a 9H-fluorene-9-one group, a dibenzothiophene 5,5-dioxide group, an azaindene group, an azaindole group, an azabenzofuran group, an azabenzothiophene group, an azabenzosilole group, an azabenzoborole group, an azabenzophosphole group, an azabenzogermole group, an azabenzoselenophene group, an azafluorene group, an azacarbazole group, an azadibenzofuran group, an azadibenzothiophene group, an azadibenzosilole group, an azadibenzoborole group, an azadibenzophosphole group, an azadibenzogermole group, an azadibenzoselenophene group, an azabenzofluorene group, an azabenzocarbazole group, an azanaphthobenzofuran group, an azanaphthobenzothiophene group, an azanaphthobenzosilole group, an azanaphthobenzoborole group, an azanaphthobenzophosphole group, an azanaphthobenzogermole group, an azanaphthobenzoselenophene group, an azadibenzofluorene group, an azadibenzocarbazole group, an azadinaphthofuran group, an azadinaphthothiophene group, an azadinaphthosilole group, an azadinaphthoborole group, an azadinaphthophosphole group, an azadinaphthogermole group, an azadinaphthoselenophene group, an azaindenophenanthrene group, an azaindolophenanthrene group, an azaphenanthrobenzofuran group, an azaphenanthrobenzothiophene group, an azaphenanthrobenzosilole group, an azaphenanthrobenzoborole group, an azaphenanthrobenzophosphole group, an azaphenanthrobenzogermole group, an azaphenanthrobenzoselenophene group, an azadibenzothiophene 5-oxide group, an aza9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a benzoquinoline group, a benzoisoquinoline group, a benzoquinoxaline group, a benzoquinazoline group, a phenanthroline group, a phenanthridine group, a pyrrole group, a pyrazole group, an imidazole group, a triazole group, an oxazole group, an isoxazole group, a thiazole group, an isothiazole group, an oxadiazole group, a thiadiazole group, an azasilole group, an azaborole group, an azaphosphole group, an azagermole group, an azaselenophene group, a benzopyrrole group, a benzopyrazole group, a benzimidazole group, a benzoxazole group, a benzisoxazole group, a benzothiazole group, a benzisothiazole group, a benzoxadiazole group, a benzothiadiazole group, a pyridinopyrrole group, a pyridinopyrazole group, a pyridinoimidazole group, a pyridinooxazole group, a pyridinoisoxazole group, a pyridinothiazole group, a pyridinoisothiazole group, a pyridinooxadiazole group, a pyridinothiadiazole group, a pyrimidinopyrrole group, a pyrimidinopyrazole group, a pyrimidinoimidazole group, a pyrimidinooxazole group, a pyrimidinoisoxazole group, a pyrimidinothiazole group, a pyrimidinoisothiazole group, a pyrimidinooxadiazole group, a pyrimidinothiadiazole group, a naphthopyrrole group, a naphthopyrazole group, a naphthoimidazole group, a naphthooxazole group, a naphthoisoxazole group, a naphthothiazole group, a naphthoisothiazole group, a naphthooxadiazole group, a naphthothiadiazole group, a phenanthrenopyrrole group, a phenanthrenopyrazole group, a phenanthrenoimidazole group, a phenanthrenooxazole group, a phenanthrenoisoxazole group, a phenanthrenothiazole group, a phenanthrenoisothiazole group, a phenanthrenooxadiazole group, a phenanthrenothiadiazole group, a 5,6,7,8-tetrahydroisoquinoline group, a 5,6,7,8-tetrahydroquinoline group, an adamantane group, a norbornane group, a norbornene group, a benzene group condensed with a cyclohexane group, a benzene group condensed with a norbornane group, a pyridine group condensed with a cyclohexane group, or a pyridine group condensed with a norbornane group.

In one or more embodiments, ring CY₁ and ring CY₃ in Formula 1 may each independently be:
a benzene group, a naphthalene group, a phenanthrene group, a dibenzofuran group, a dibenzothiophene group, a dibenzoselenophene group, a carbazole group, a fluorene group, or a dibenzosilole group; or
a benzene group, a naphthalene group, a phenanthrene group, a dibenzofuran group, a dibenzothiophene group, a dibenzoselenophene group, a carbazole group, a fluorene group, or a dibenzosilole group, each condensed with a cyclohexane group, a cyclohexene group, a norbornane group, a piperidine group, or a combination thereof.

In one or more embodiments, ring CY₂ in Formula 1 may be:
an imidazole group, a benzimidazole group, a pyridine group, a pyrimidine group, a pyridazine group, a pyrazine group, a triazine group, a quinoline group, an isoquinoline group, a quinoxaline group, or a quinazoline group; or
an imidazole group, a benzimidazole group, a pyridine group, a pyrimidine group, a pyridazine group, a pyrazine group, a triazine group, a quinoline group, an isoquinoline group, a quinoxaline group, or a quinazoline group, each condensed with a cyclohexane group, a cyclohexene group, a norbornane group, a benzene group, a pyridine group, a pyrimidine group, or a combination thereof.

In one or more embodiments, ring CY₄ in Formula 1 may be:
a pyridine group, a pyrimidine group, a pyridazine group, a pyrazine group, a triazine group, a quinoline group, an isoquinoline group, a quinoxaline group, a quinazoline group, an azadibenzofuran group, an azadibenzothiophene group, an azadibenzoselenophene group, an azacarbazole group, an azafluorene group, or an azadibenzosilole group; or a pyridine group, a pyrimidine group, a pyridazine group, a pyrazine group, a triazine group, a quinoline group, an isoquinoline group, a quinoxaline group, a quinazoline group, an azadibenzofuran group, an azadibenzothiophene group, an azadibenzoselenophene group, an azacarbazole group, an azafluorene group, or an azadibenzosilole group, each condensed with a cyclohexane group, a cyclohexene group, a norbornane group, a benzene group, a pyridine group, a pyrimidine group, or a combination thereof.

Ring A₁ and ring A₃ in Formulae 2-1 and 2-2 may be different from each other.

In one or more embodiments, a Y₁-containing monocyclic group in ring A₁, a Y₂-containing monocyclic group in ring A₂, and Y₄-containing monocyclic group in ring A₄ may each be a 6-membered ring.

In one or more embodiments, a Y₃-containing monocyclic group in ring A₃ may be a 6-membered ring.

In one or more embodiments, a Y₃-containing monocyclic group in ring A₃ may be a 5-membered ring.

In one or more embodiments, a Y₁-containing monocyclic group in ring A₁ may be a 6-membered ring, and a Y₃-containing monocyclic group in ring A₃ may be a 5-membered ring.

In one or more embodiments, ring A₁ and ring A₃ in Formulae 2-1 and 2-2 may each independently be i) an A group, ii) a polycyclic group in which two or more A groups are condensed with each other, or iii) a polycyclic group in which at least one A group and at least one B group are condensed with each other,
the A group may be a pyridine group, a pyrimidine group, a pyridazine group, a pyrazine group, or a triazine group, and
the B group may be a cyclohexane group, a cyclohexene group, a norbornane group, a benzene group, a furan group, a thiophene group, a selenophene group, a pyrrole group, a cyclopentadiene group, or a silole group.

In one or more embodiments, in Formula 2-2, ring A₃ may be i) a C group, ii) a polycyclic group in which two or more C groups are condensed with each other, or iii) a polycyclic group in which at least one C group and at least one D group are condensed with each other,
the C group may be a pyrrole group, a pyrazole group, an imidazole group, a triazole group, an oxazole group, an isoxazole group, a thiazole group, or an isothiazole group, and
the D group may be a cyclohexane group, a cyclohexene group, a norbornane group, a benzene group, a furan group, a thiophene group, a selenophene group, a cyclopentadiene group, a silole group, a pyridine group, a pyrimidine group, a pyridazine group, a pyrazine group, or a triazine group.

In one or more embodiments, ring A₁ in Formula 2-1 may be:
a pyridine group, a pyrimidine group, a pyridazine group, or a pyrazine group; or
a pyridine group, a pyrimidine group, a pyridazine group, or a pyrazine group, each condensed with at least one of a cyclohexane group, a norbornane group, a benzene group, or a combination thereof.

In one or more embodiments, ring A₃ in Formula 2-2 may be:
a pyridine group, a pyrimidine group, a pyridazine group, or a pyrazine group;
a pyridine group, a pyrimidine group, a pyridazine group, or a pyrazine group, each condensed with at least one of a cyclohexane group, a norbornane group, a benzene group, or a combination thereof; or
an imidazole group, a benzimidazole group, a naphthoimidazole group, a phenanthrenoimidazole group, a pyridoimidazole group, an oxazole group, a benzoxazole group, a naphthooxazole group, a phenanthrenooxazole group, a pyridooxazole group, a thiazole group, a benzothiazole group, a naphthothiazole group, a phenanthrenothiazole group, or a pyridothiazole group.

In one or more embodiments, ring A₂ and ring A₄ in Formulae 2-1 and 2-2 may be different from each other.

In one or more embodiments, ring A₂ and ring A₄ in Formulae 2-1 and 2-2 may each independently be i) an E group, ii) a polycyclic group in which two or more E groups are condensed with each other, or iii) a polycyclic group in which at least one E group and at least one F group are condensed with each other,
the E group may be a benzene group, a pyridine group, a pyrimidine group, a pyridazine group, a pyrazine group, or a triazine group, and
the F group may be a furan group, a thiophene group, a selenophene group, a pyrrole group, a cyclopentadiene group, a silole group, a pyrazole group, an imidazole group, an oxazole group, a thiazole group, an isoxazole group, or an isothiazole group.

In one or more embodiments, ring A₂ in Formula 2-1 may be a polycyclic group in which two or more E groups and at least one F group are condensed with each other.

In one or more embodiments, ring A₄ in Formula 2-2 may be a polycyclic group in which two or more E groups and at least one F group are condensed with each other.

In one or more embodiments, ring A₂ in Formula 2-1 may be:
a benzene group, a naphthalene group, a phenanthrene group, a dibenzofuran group, a dibenzothiophene group, a dibenzoselenophene group, a carbazole group, a fluorene group, or a dibenzosilole group; or
a benzene group, a naphthalene group, a phenanthrene group, a dibenzofuran group, a dibenzothiophene group, a dibenzoselenophene group, a carbazole group, a fluorene group, or a dibenzosilole group, each condensed with at least one of a cyclohexane group, a norbornane group, a benzene group, or a combination thereof.

In one or more embodiments, ring A₄ in Formula 2-2 may be:
a benzene group, a naphthalene group, a phenanthrene group, a dibenzofuran group, a dibenzothiophene group, a dibenzoselenophene group, a carbazole group, a fluorene group, a dibenzosilole group, an azadibenzofuran group, an azadibenzothiophene group, an azadibenzoselenophene group, an azacarbazole group, an azafluorene group, or a dibenzosilole group; or
a benzene group, a naphthalene group, a phenanthrene group, a dibenzofuran group, a dibenzothiophene group, a dibenzoselenophene group, a carbazole group, a fluorene group, a dibenzosilole group, an azadibenzofuran group, an azadibenzothiophene group, an azadibenzoselenophene group, an azacarbazole group, an azafluorene group, or a dibenzosilole group, each condensed with at least one of a benzene group, a pyridine group, a pyrimidine group, a pyridazine group, a pyrazine group, a cyclohexane group, a norbornane group, a furan group, a thiophene group, a selenophene group, a pyrrole group, a cyclopentadiene group, a silole group, a pyrazole group, an imidazole group, an oxazole group, a thiazole group, an isoxazole group, an isothiazole group, or a combination thereof.

T₁₁ to T₁₄ in Formula 1 may each independently be a single bond, a double bond, *—N(R₅ₐ)—*′, *—B(R₅ₐ)—*′, *—P(R₅ₐ)—*′, *—C(R₅ₐ)(R_{5b})—*′, *—Si(R₅ₐ)(R_{5b})—*′, *—Ge(R₅ₐ)(R_{5b})—*′, *—S—*′, *—Se—*′, *—O—*′, *—C(═O)—*′, *—S(═O)—*′, *—S(═O)₂—*, *—C(R₅ₐ)═*′, *═C(R₅ₐ)—*′, *—C(R₅ₐ)═C(R_{5b})—*, *—C(═S)—*′, *—C≡C—*′, a C₅-C₃₀ carbocyclic group unsubstituted or substituted with at least one R₁₀ₐ, or a C₁-C₃₀ heterocyclic group unsubstituted or substituted with at least one R₁₀ₐ.

For example, T₁₁ and T₁₂ in Formula 1 may each be a single bond, and T₁₃ may be a single bond, *—N(R₅ₐ)—*′, *—B(R₅ₐ)—*′, *—P(R₅ₐ)—*′, *—C(R₅ₐ)(R_{5b})—*′, *—Si(R₅ₐ)(R_{5b})—*′, *—Ge(R₅ₐ)(R_{5b})—*′, *—S—*′, or *—O—*′.

n1 to n4 in Formula 1 indicate the numbers of T₁₁ to T₁₄, respectively, and may each independently be 0 or 1, wherein three or more of n1 to n4 may each be 1. That is, the organometallic compound represented by Formula 1 may have a tetradentate ligand.

In Formula 1, when n1 is 0, T₁₁ may not exist (that is, ring CY₁ and ring CY₂ are not connected to each other), when n2 is 0, T₁₂ may not exist (that is, ring CY₂ and ring CY₃ are not connected to each other), when n3 is 0, T₁₃ may not exist (that is, ring CY₃ and ring CY₄ are not connected to each other), and when n4 is 0, T₁₄ may not exist (that is, ring CY₄ and ring CY₁ are not connected to each other).

In one or more embodiments, in Formula 1, n1 to n3 may each be 1, and n4 may be 0.

L₁ to L₄ and W₁ to W₄ in Formulae 1, 2-1, and 2-2 may each independently be a single bond, a C₁-C₂₀ alkylene group unsubstituted or substituted with at least one R₁₀ₐ, a C₅-C₃₀ carbocyclic group unsubstituted or substituted with at least one R₁₀ₐ, or a C₁-C₃₀ heterocyclic group unsubstituted or substituted with at least one R₁₀ₐ.

For example, L₁ to L₄ and W₁ to W₄ in Formulae 1, 2-1, and 2-2 may each independently be:
a single bond; or
a C₁-C₂₀ alkylene group, a cyclopentene group, a cyclohexane group, a cyclohexene group, a benzene group, a naphthalene group, an anthracene group, a phenanthrene group, a triphenylene group, a pyrene group, a chrysene group, a cyclopentadiene group, a 1,2,3,4-tetrahydronaphthalene group, a thiophene group, a furan group, an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluorene-9-one group, a dibenzothiophene 5,5-dioxide group, an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an iso-oxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, a 5,6,7,8-tetrahydroquinoline group, an adamantane group, a norbornane group, or a norbornene group, each unsubstituted or substituted with at least one R₁₀ₐ.

In one or more embodiments, L₁ to L₄ and W₁ to W₄ in Formulae 1, 2-1, and 2-2 may each independently be:
a single bond; or
a C₁-C₂₀ alkylene group, a benzene group, a naphthalene group, a pyridine group, a fluorene group, a carbazole group, a dibenzofuran group, or a dibenzothiophene group, each unsubstituted or substituted with at least one R₁₀ₐ.

In one or more embodiments, L₁ to L₄ and W₁ to W₄ in Formulae 1, 2-1, and 2-2 may each independently be:
a single bond; or
a C₁-C₂₀ alkylene group, a benzene group, a naphthalene group, a dibenzofuran group, or a dibenzothiophene group, each unsubstituted or substituted with deuterium, —F, a cyano group, a C₁-C₂₀ alkyl group, a deuterated C₁-C₂₀ alkyl group, a fluorinated C₁-C₂₀ alkyl group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a phenyl group, a deuterated phenyl group, a fluorinated phenyl group, a (C₁-C₂₀ alkyl)phenyl group, a naphthyl group, a pyridinyl group, a furanyl group, a thiophenyl group, a benzofuranyl group, a benzothiophenyl group, a dibenzofuranyl group, a dibenzothiophenyl group, or a combination thereof.

b1 to b4 in Formula 1 indicate the number of L₁(s) to the number of L₄(s), respectively, and may each independently be an integer from 1 to 10. When b1 is 2 or more, two or more of L₁(s) may be identical to or different from each other, when b2 is 2 or more, two or more of L₂(s) may be identical to or different from each other, when b3 is 2 or more, two or more of L₃(s) may be identical to or different from each other, and when b4 is 2 or more, two or more of L₄(s) may be identical to or different from each other. For example, b1 to b4 may each independently be 1, 2, or 3.

R₁ to R₄, R₅ₐ, R_{5b}, R′, R″, and Z₁ to Z₄ in Formulae 1, 2-1, and 2-2 may each independently be hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ heteroarylalkyl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉). Q₁ to Q₉ are respectively the same as those described in the present specification.

In one or more embodiments, R₁ to R₄, R₅ₐ, R_{5b}, R, R″, and Z₁ to Z₄ in Formulae 1, 2-1, and 2-2 may each independently be:
hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₁-C₂₀ alkoxy group, or a C₁-C₂₀ alkylthio group;
a C₁-C₂₀ alkyl group, a C₂-C₂₀ alkenyl group, a C₁-C₂₀ alkoxy group, or a C₁-C₂₀ alkylthio group, each substituted with at least one of deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.1]heptyl group, a (C₁-C₂₀ alkyl)bicyclo[2.2.2]octyl group, a phenyl group, a (C₁-C₂₀ alkyl)phenyl group, a biphenyl group, a terphenyl group, a naphthyl group, a pyridinyl group, a pyrimidinyl group, or a combination thereof;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a phenyl group, a (C₁-C₂₀ alkyl)phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, or an azadibenzothiophenyl group, each unsubstituted or substituted with at least one of deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a deuterated C₁-C₂₀ alkyl group, a fluorinated C₁-C₂₀ alkyl group, a C₁-C₂₀ alkoxy group, a C₁-C₂₀ alkylthio group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.1]heptyl group, a (C₁-C₂₀ alkyl)bicyclo[2.2.2]octyl group, a phenyl group, a (C₁-C₂₀ alkyl)phenyl group, a deuterated phenyl group, a fluorinated phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, or a combination thereof; or
—N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉), and
Q₁ to Q₉ may each independently be:
deuterium, —F, —CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, —CD₂CDH₂, —CF₃, —CF₂H, —CFH₂, —CH₂CF₃, —CH₂CF₂H, —CH₂CFH₂, —CHFCH₃, —CHFCF₂H, —CHFCFH₂, —CHFCF₃, —CF₂CF₃, —CF₂CF₂H, or —CF₂CFH₂; or
an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, a phenyl group, a biphenyl group, or a naphthyl group, each unsubstituted or substituted with deuterium, —F, a C₁-C₁₀ alkyl group, a phenyl group, or a combination thereof.

In one or more embodiments, R₁ to R₄, R₅ₐ, R_{5b}, R′, R″, and Z₁ to Z₄ in Formulae 1, 2-1, and 2-2 may each independently be:
hydrogen, deuterium, —F, or a cyano group;
a C₁-C₂₀ alkyl group unsubstituted or substituted with at least one of deuterium, —F, a cyano group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a C₁-C₁₀ heterocycloalkyl group, a deuterated C₁-C₁₀ heterocycloalkyl group, a fluorinated C₁-C₁₀ heterocycloalkyl group, a (C₁-C₂₀ alkyl)C₁-C₁₀ heterocycloalkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, a dibenzofuranyl group, a deuterated dibenzofuranyl group, a fluorinated dibenzofuranyl group, a (C₁-C₂₀ alkyl)dibenzofuranyl group, a dibenzothiophenyl group, a deuterated dibenzothiophenyl group, a fluorinated dibenzothiophenyl group, a (C₁-C₂₀ alkyl)dibenzothiophenyl group, or a combination thereof;
a C₃-C₁₀ cycloalkyl group, a C₁-C₁₀ heterocycloalkyl group, a phenyl group, a biphenyl group, a naphthyl group, a pyridinyl group, a fluorenyl group, a carbazolyl group, a dibenzofuranyl group, or a dibenzothiophenyl group, each unsubstituted or substituted with at least one of deuterium, —F, a cyano group, a C₁-C₂₀ alkyl group, a deuterated C₁-C₂₀ alkyl group, fluorinated C₁-C₂₀ alkyl group, a C₁-C₂₀ alkoxy group, a deuterated C₁-C₂₀ alkoxy group, a fluorinated C₁-C₂₀ alkoxy group, a C₁-C₂₀ alkylthio group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a C₁-C₁₀ heterocycloalkyl group, a deuterated C₁-C₁₀ heterocycloalkyl group, a fluorinated C₁-C₁₀ heterocycloalkyl group, a (C₁-C₂₀ alkyl)C₁-C₁₀ heterocycloalkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, a dibenzofuranyl group, a deuterated dibenzofuranyl group, a fluorinated dibenzofuranyl group, a (C₁-C₂₀ alkyl)dibenzofuranyl group, a dibenzothiophenyl group, a deuterated dibenzothiophenyl group, a fluorinated dibenzothiophenyl group, a (C₁-C₂₀ alkyl)dibenzothiophenyl group, or a combination thereof; or
—Si(Q₃)(Q₄)(Q₅) or —Ge(Q₃)(Q₄)(Q₅).

In one or more embodiments, e1 and d1 in Formula 2-1 may each not be 0, and at least one of Z₁(s) may be a deuterated C₁-C₂₀ alkyl group, —Si(Q₃)(Q₄)(Q₅), or —Ge(Q₃)(Q₄)(Q₅). Q₃ to 05 are respectively the same as those described in the present specification.

For example, Q₃ to Q₅ may each independently be:
a C₁-C₆₀ alkyl group unsubstituted or substituted with at least one of deuterium, a C₁-C₆₀ alkyl group, a C₆-C₆₀ aryl group, or a combination thereof; or
a C₆-C₆₀ aryl group unsubstituted or substituted with at least one of deuterium, a C₁-C₆₀ alkyl group, a C₆-C₆₀ aryl group, or a combination thereof.

In one or more embodiments, Q₃ to Q₅ may each independently be:
—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or

an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, a phenyl group, a biphenyl group, or a naphthyl group, each unsubstituted or substituted with at least one of deuterium, a C₁-C₁₀ alkyl group, a phenyl group, or a combination thereof.

In one or more embodiments, Q₃ to Q₅ may be identical to each other.

In one or more embodiments, two or more of Q₃ to Q₅ may be different from each other.

In one or more embodiments, the iridium-containing organometallic compound may satisfy at least one of Condition 10-1 to Condition 10-8:

### Condition 10-1

each of e1 and d1 in Formula 2-1 is not 0, and at least one Z₁ includes deuterium;

### Condition 10-2

each of e2 and d2 in Formula 2-1 is not 0, and at least one Z₂ includes deuterium;

### Condition 10-3

each of e3 and d3 in Formula 2-2 is not 0, and at least one Z₃ includes deuterium;

### Condition 10-4

each of e4 and d4 in Formula 2-2 is not 0, and at least one Z₄ includes deuterium;

### Condition 10-5

each of e1 and d1 in Formula 2-1 is not 0, and at least one Z₁ includes a fluoro group;

### Condition 10-6

each of e2 and d2 in Formula 2-1 is not 0, and at least one Z₂ includes a fluoro group;

### Condition 10-7

each of e3 and d3 in Formula 2-2 is not 0, and at least one Z₃ includes a fluoro group; and

### Condition 10-8

each of e4 and d4 in Formula 2-2 is not 0, and at least one Z₄ includes a fluoro group.

In one or more embodiments, R₁ to R₄, R₅ₐ, R_{5b}, R′, R″, and Z₁ to Z₄ in Formulae 1, 2-1, and 2-2 may each independently be hydrogen, deuterium, —F, —CH₃, —CD₃, —CD₂H, —CDH₂, —CF₃, —CF₂H, —CFH₂, a C₂-C₁₀ alkenyl group, a C₁-C₁₀ alkoxy group, a C₁-C₁₀ alkylthio group, a group represented by one of Formulae 9-1 to 9-39, a group represented by one of Formulae 9-1 to 9-39 in which at least one hydrogen is substituted with deuterium, a group represented by one of Formulae 9-1 to 9-39 in which at least one hydrogen is substituted with —F, a group represented by one of Formulae 9-201 to 9-227, a group represented by one of Formulae 9-201 to 9-227 in which at least one hydrogen is substituted with deuterium, a group represented by one of Formulae 9-201 to 9-227 in which at least one hydrogen is substituted with —F, a group represented by one of Formulae 10-1 to 10-129, a group represented by one of Formulae 10-1 to 10-129 in which at least one hydrogen is substituted with deuterium, a group represented by one of Formulae 10-1 to 10-129 in which at least one hydrogen is substituted with —F, a group represented by one of Formulae 10-201 to 10-350, a group represented by one of Formulae 10-201 to 10-350 in which at least one hydrogen is substituted with deuterium, a group represented by one of Formulae 10-201 to 10-350 in which at least one hydrogen is substituted with —F, —Si(Q₃)(Q₄)(Q₅), or —Ge(Q₃)(Q₄)(Q₅) (wherein Q₃ to Q₅ are respectively the same as those described in the present specification):

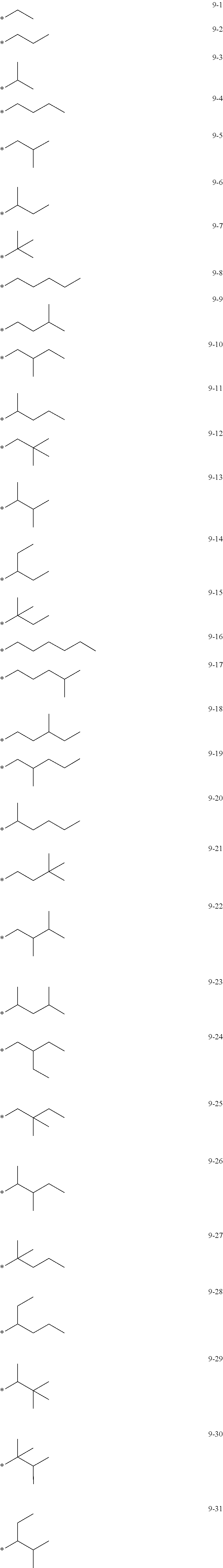

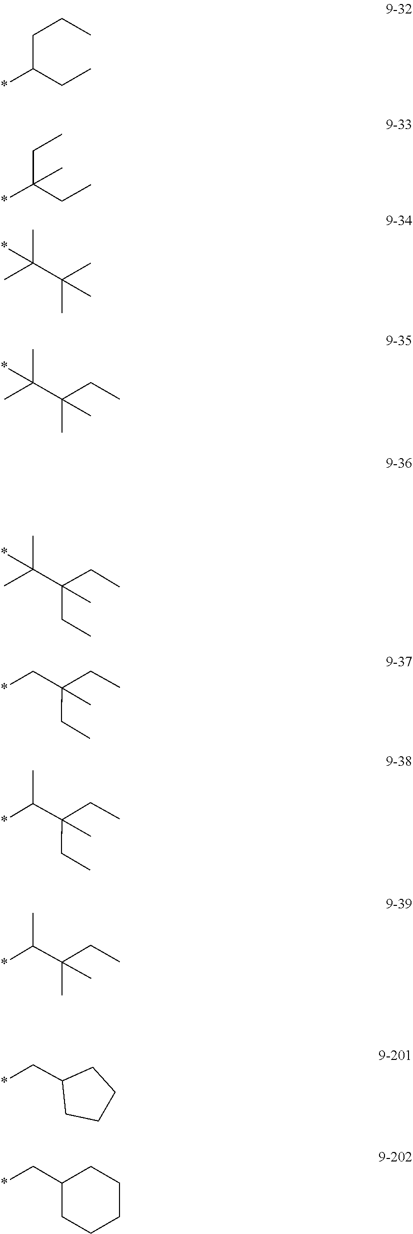

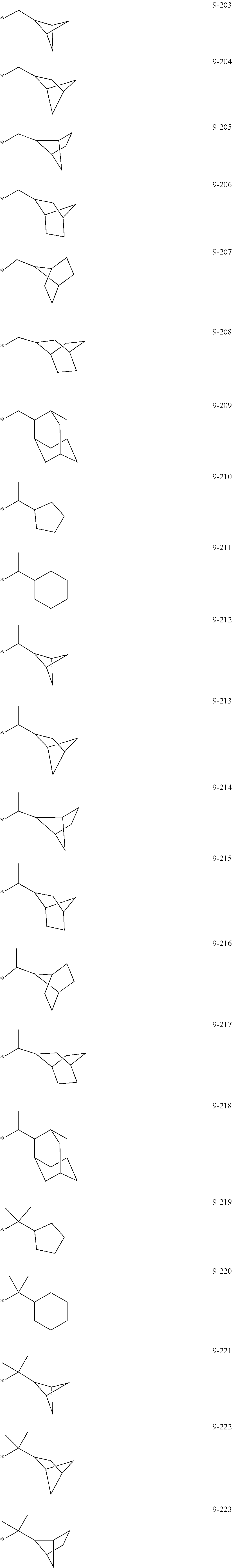

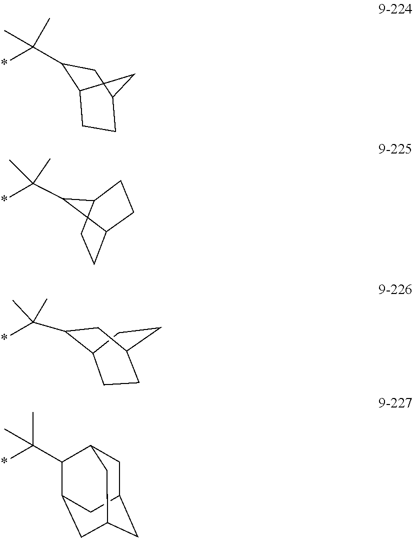

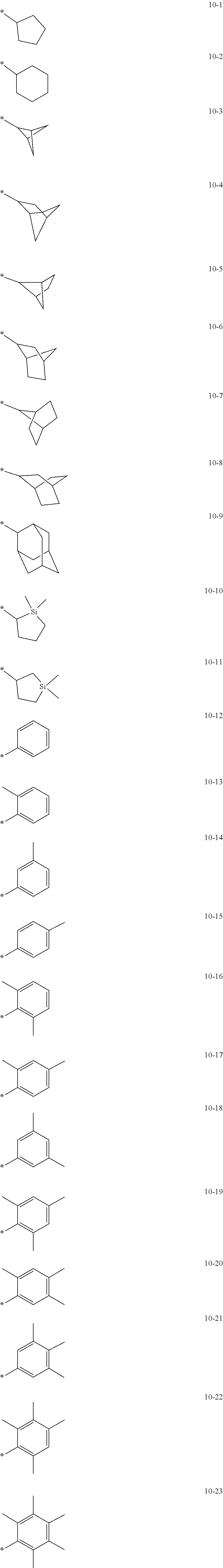

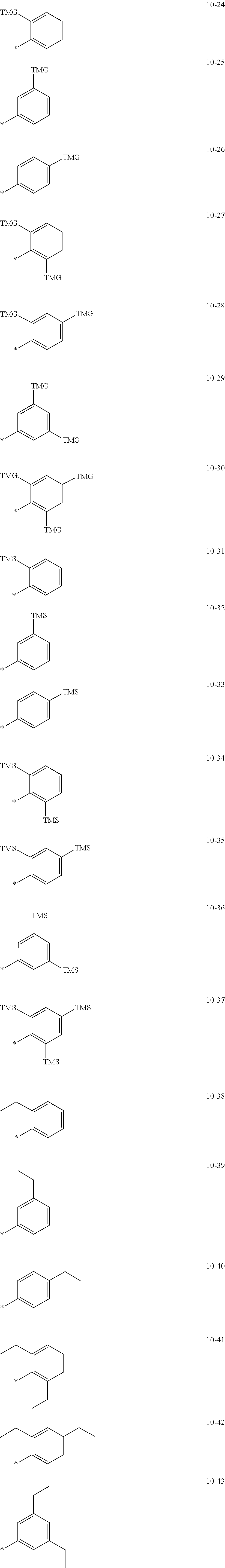

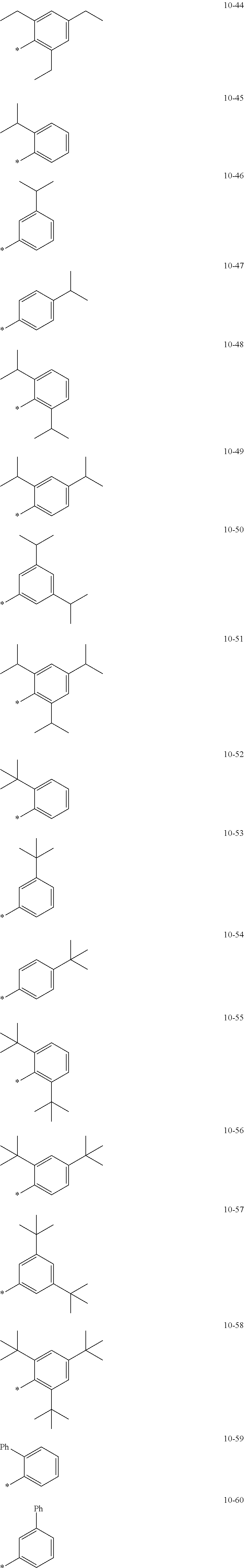

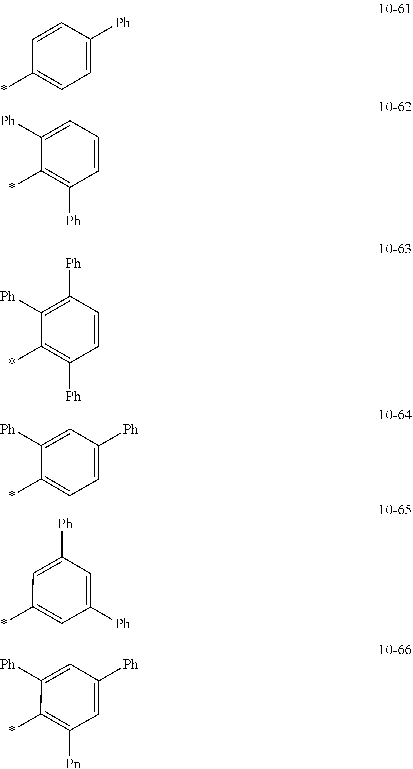

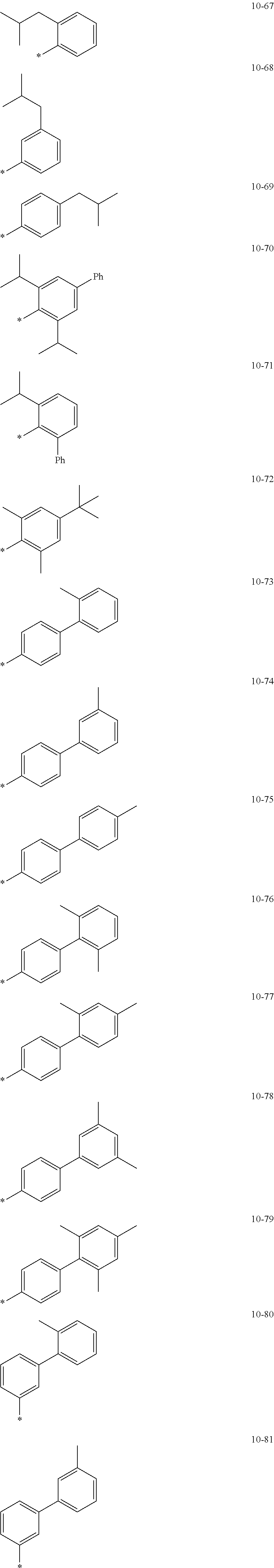

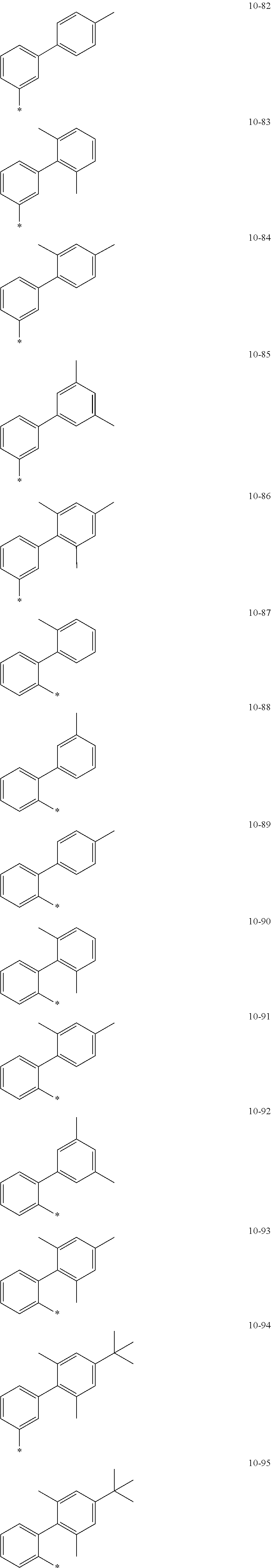

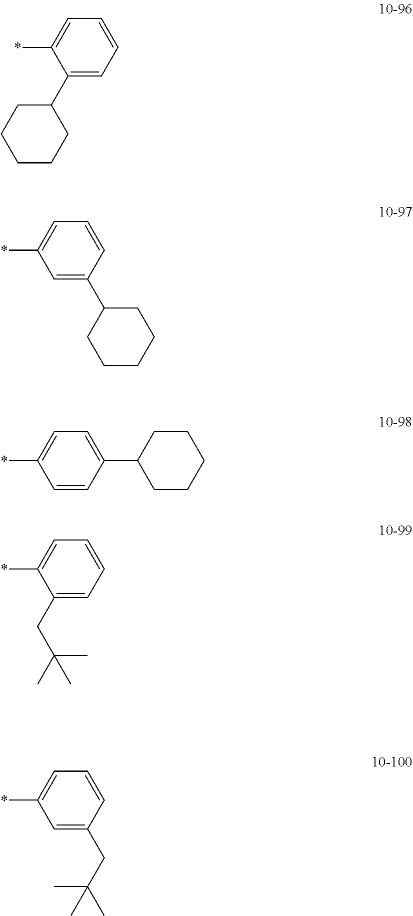

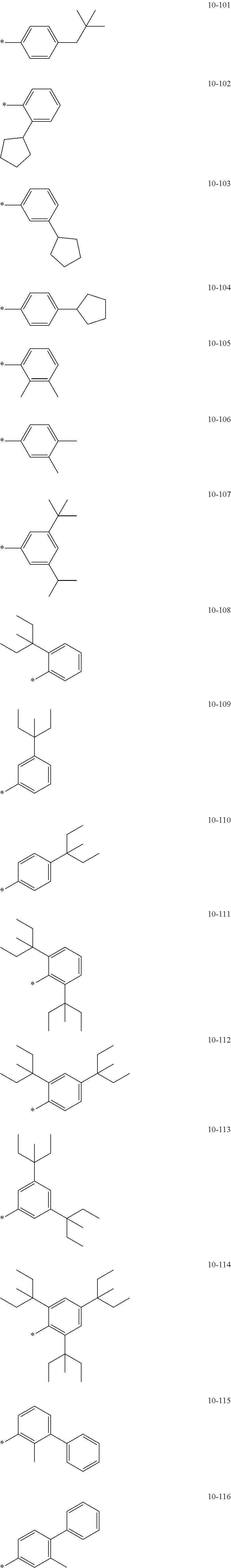

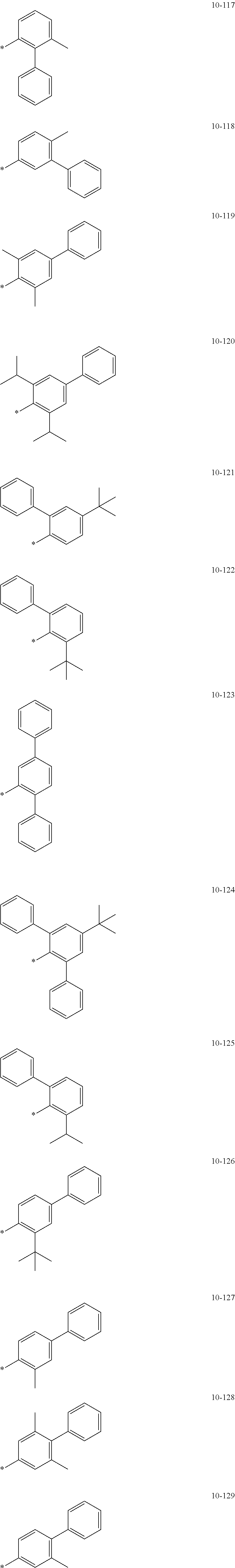

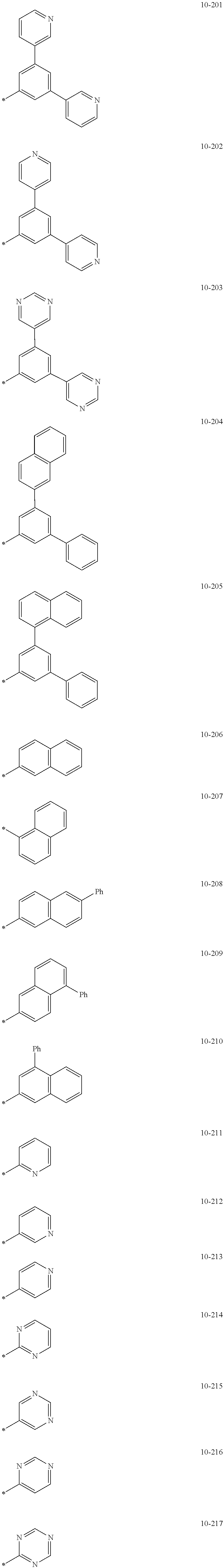

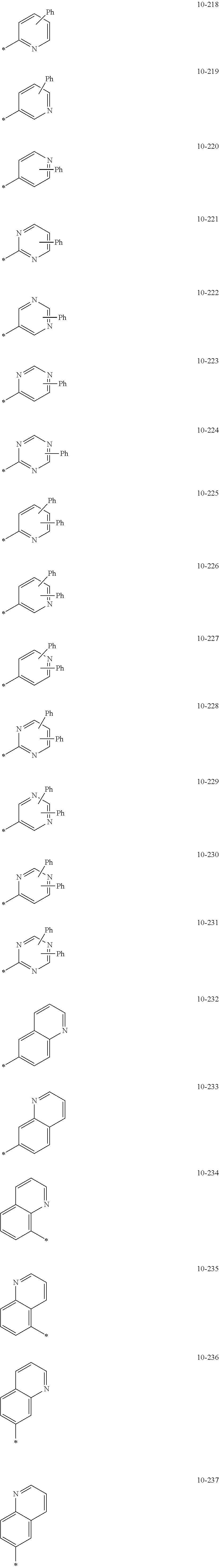

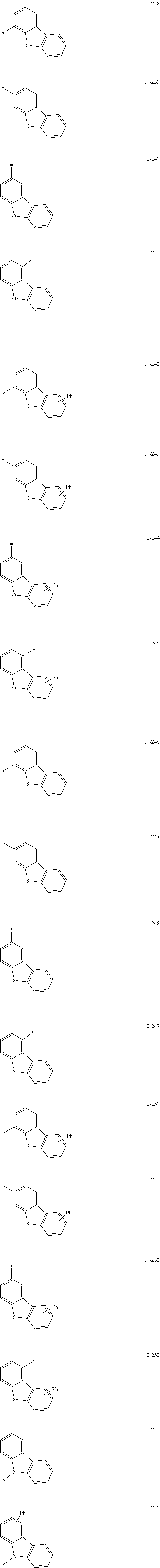

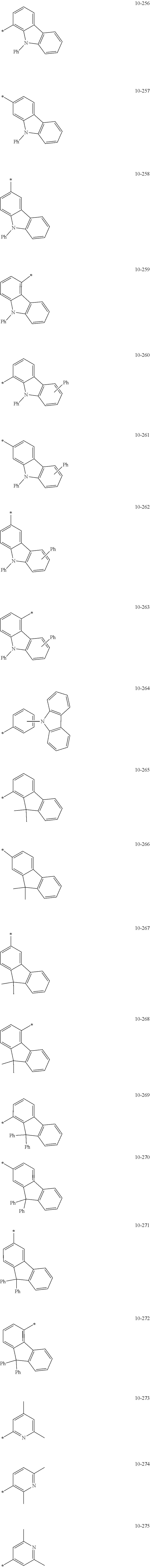

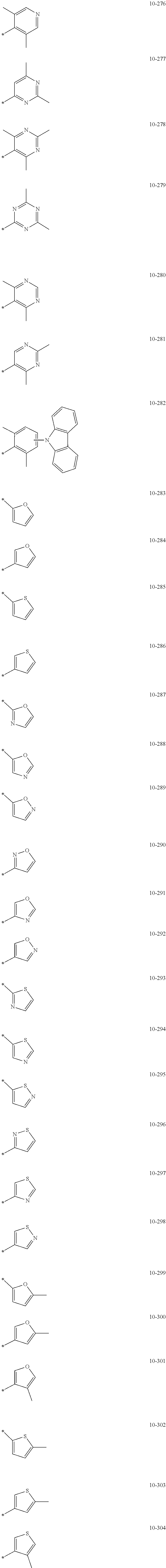

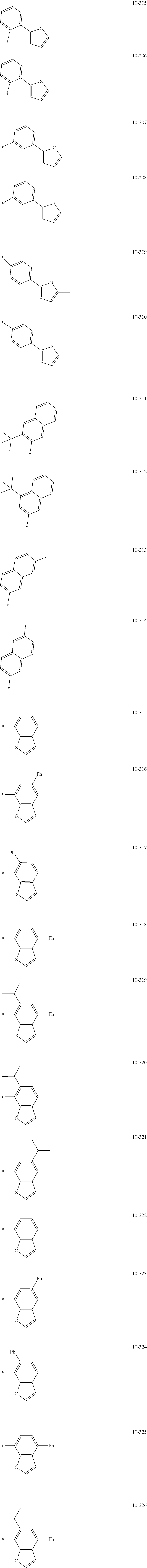

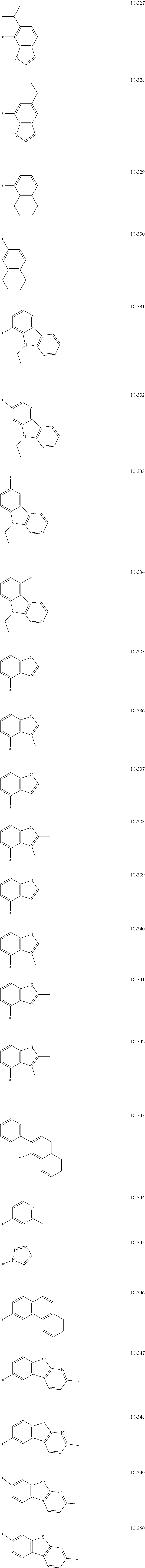

wherein, in Formulae 9-1 to 9-39, 9-201 to 9-227, 10-1 to 10-129, and 10-201 to 10-350, * indicates a binding site to an adjacent atom, “Ph” is a phenyl group, “TMS” is a trimethylsilyl group, and “TMG” is a trimethylgermyl group.

The “group represented by one of Formulae 9-1 to 9-39 in which at least one hydrogen is substituted with deuterium” and the “group represented by one of Formulae 9-201 to 9-227 in which at least one hydrogen is substituted with deuterium” may each be, for example, a group represented by one of Formulae 9-501 to 9-514 and 9-601 to 9-636:

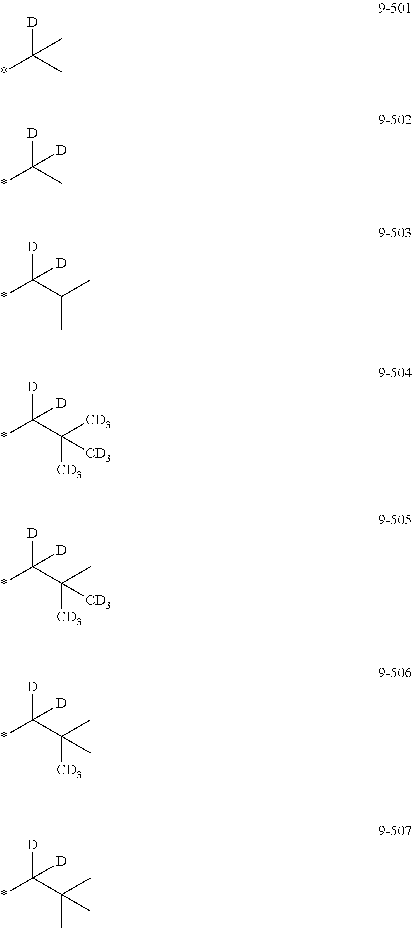

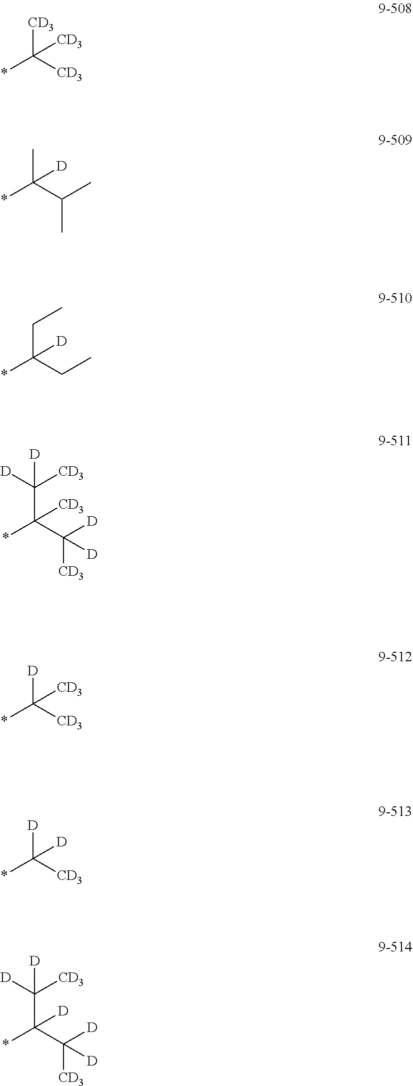

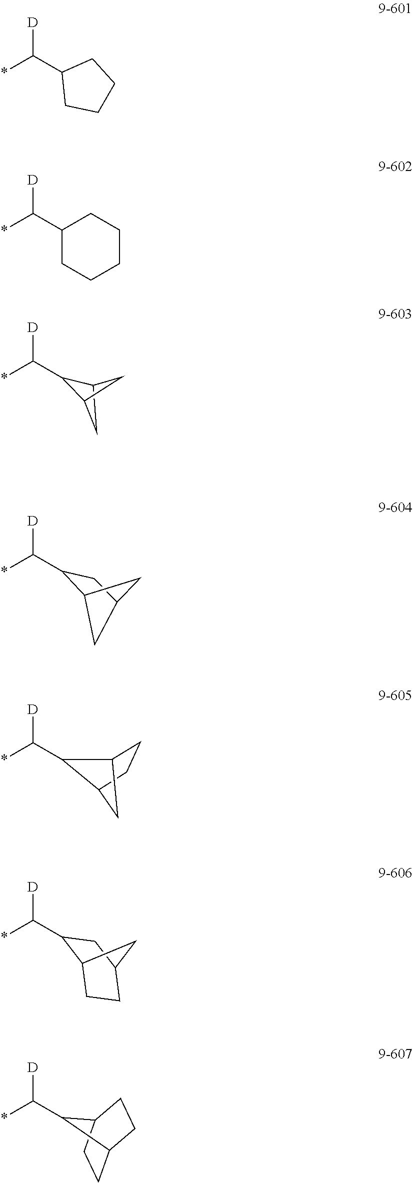

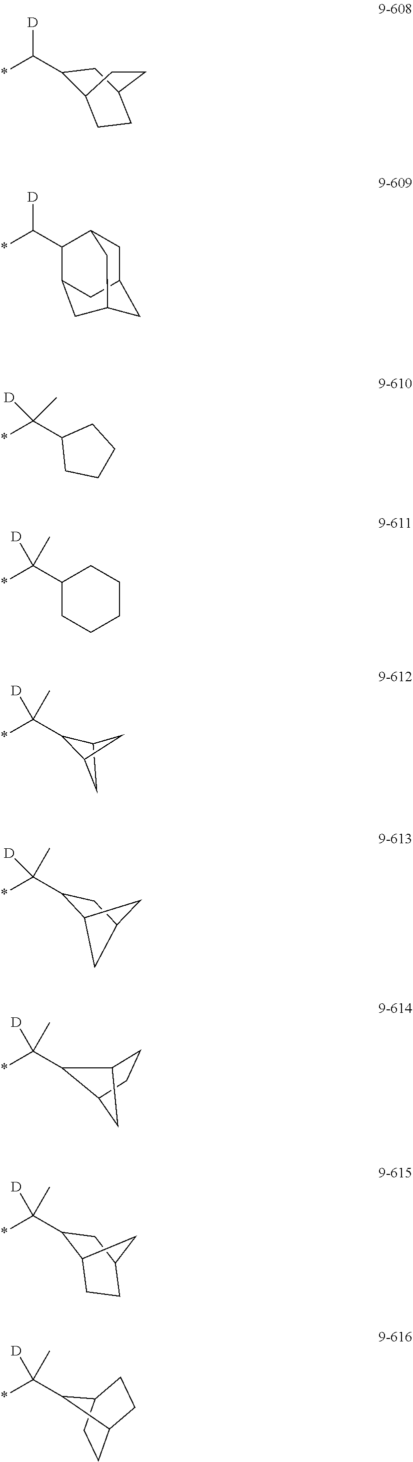

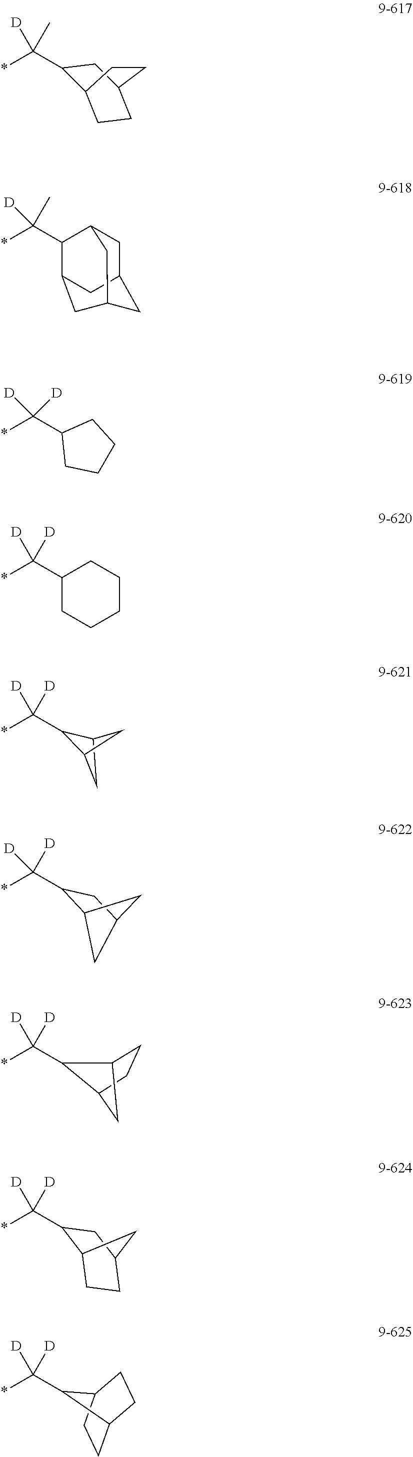

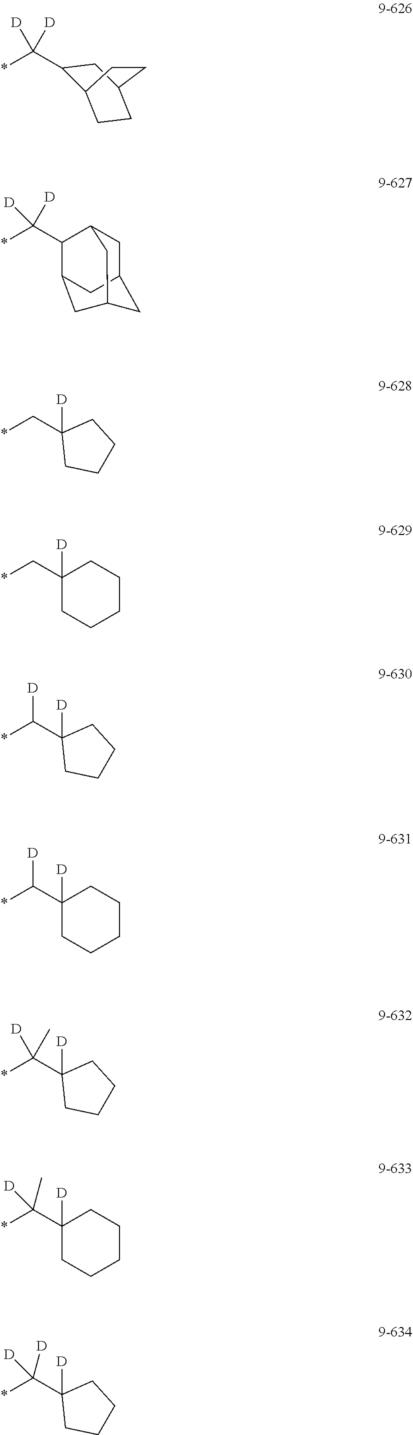

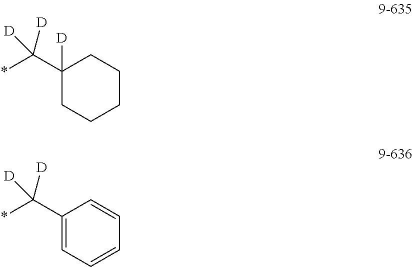 [SMILES: *C([2H])([2H])C1([2H])CCCCC1 ; *C([2H])([2H])c1ccccc1]

The “group represented by one of Formulae 9-1 to 9-39 in which at least one hydrogen is substituted with —F” and the “group represented by one of Formulae 9-201 to 9-227 in which at least one hydrogen is substituted with —F” may each be, for example, a group represented by one of Formulae 9-701 to 9-710:

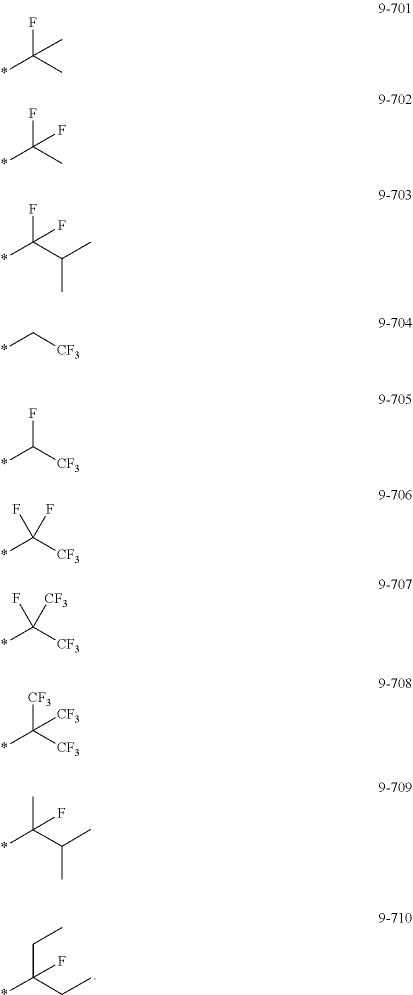

The “group represented by one of Formulae 10-1 to 10-129 in which at least one hydrogen is substituted with deuterium” and “the group represented by one of Formulae 10-201 to 10-350 in which at least one hydrogen is substituted with deuterium” may each be, for example, a group represented by one of Formulae 10-501 to 10-553:

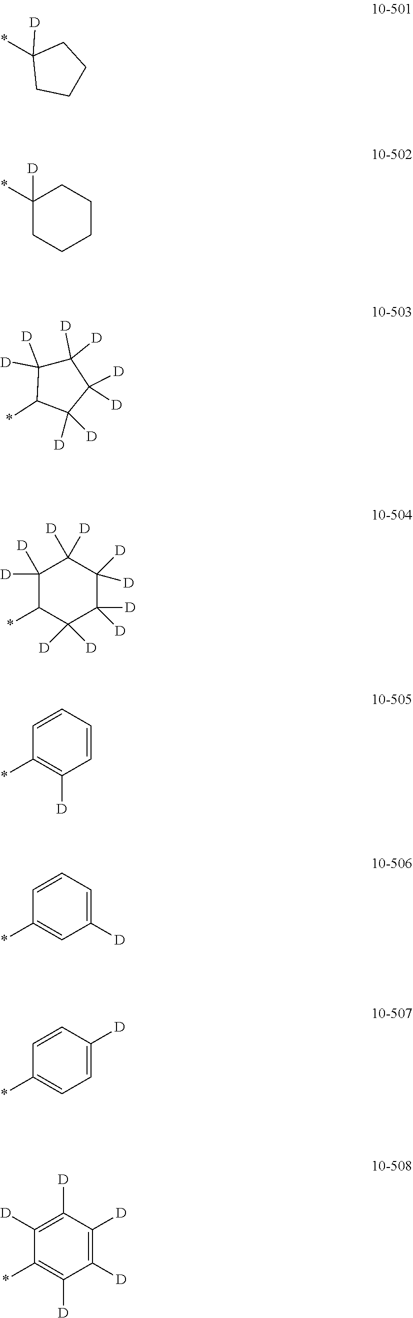

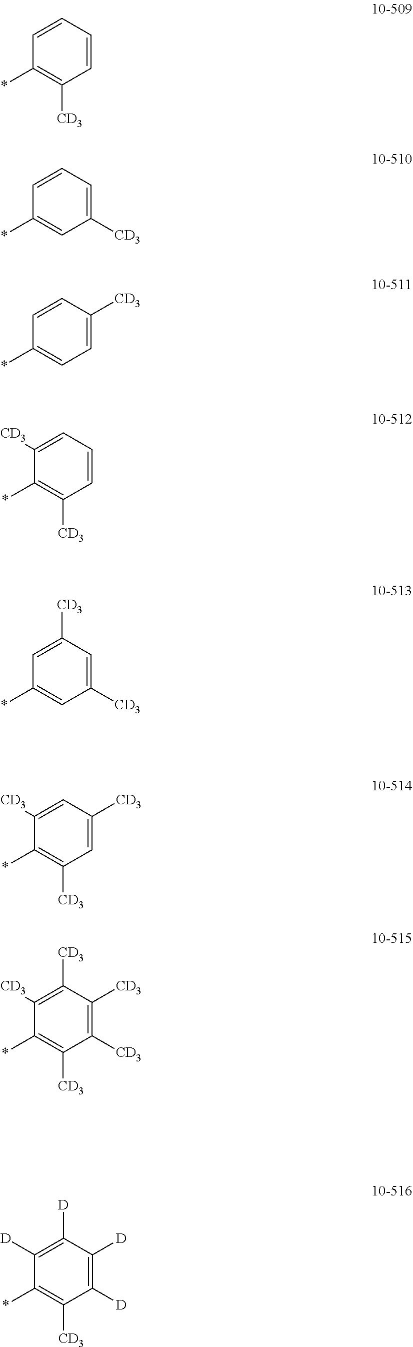

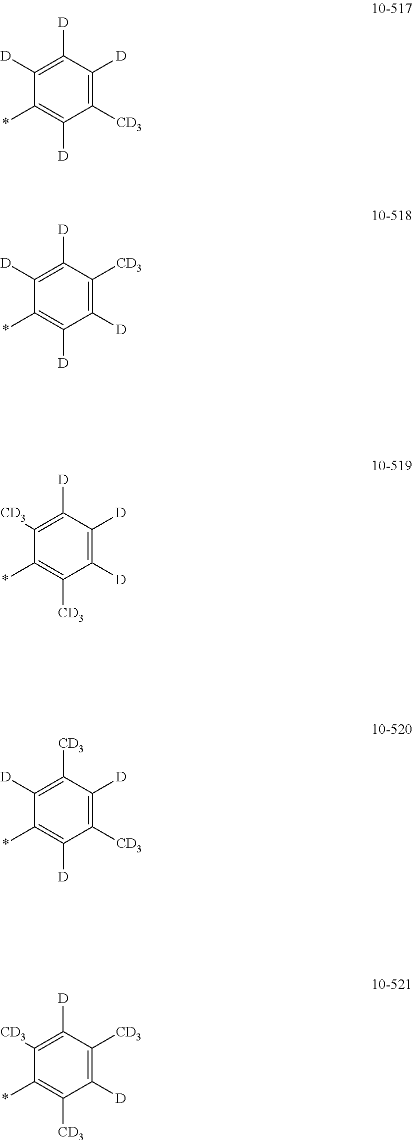 [SMILES: *c1c([2H])c([2H])c([2H])c(C([2H])([2H])[2H])c1[2H] ; *c1c([2H])c([2H])c(C([2H])([2H])[2H])c([2H])c1[2H] ; *c1c(C([2H])([2H])[2H])c([2H])c([2H])c([2H])c1C([2H])([2H])[2H] ; *c1c([2H])c(C([2H])([2H])[2H])c([2H])c(C([2H])([2H])[2H])c1[2H] ; *c1c(C([2H])([2H])[2H])c([2H])c(C([2H])([2H])[2H])c([2H])c1C([2H])([2H])[2H]]

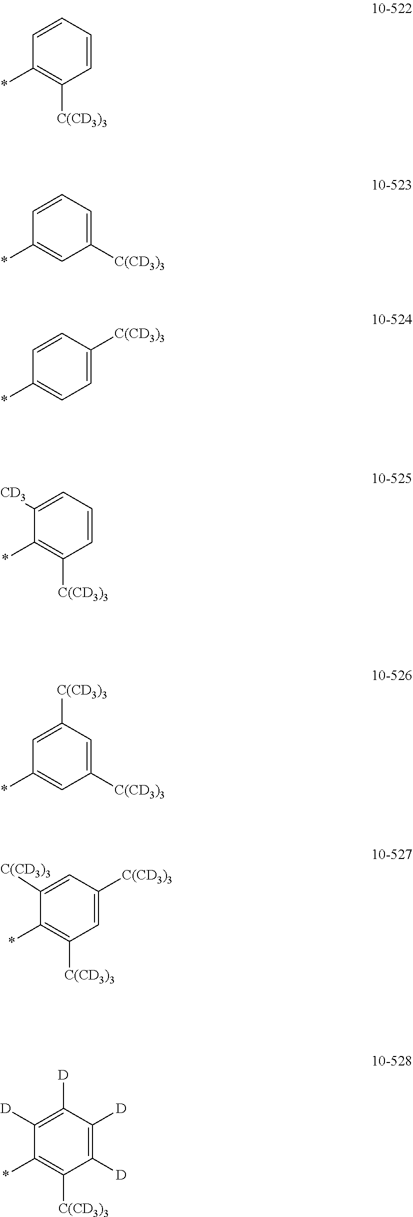

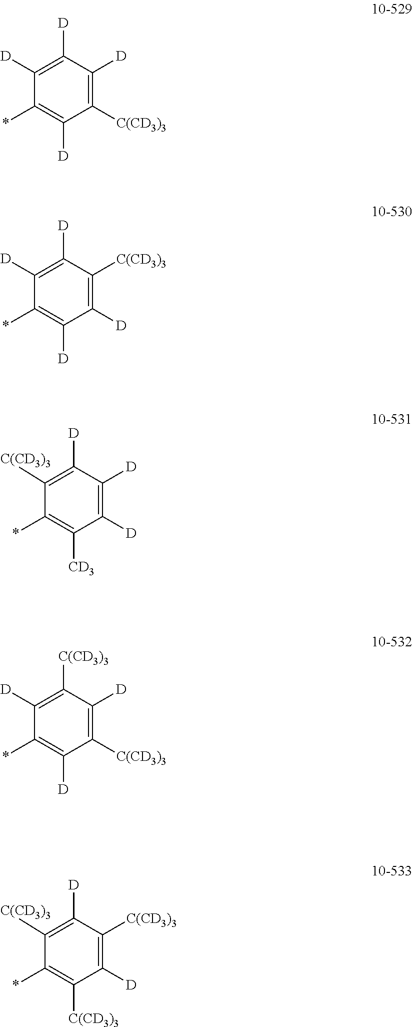

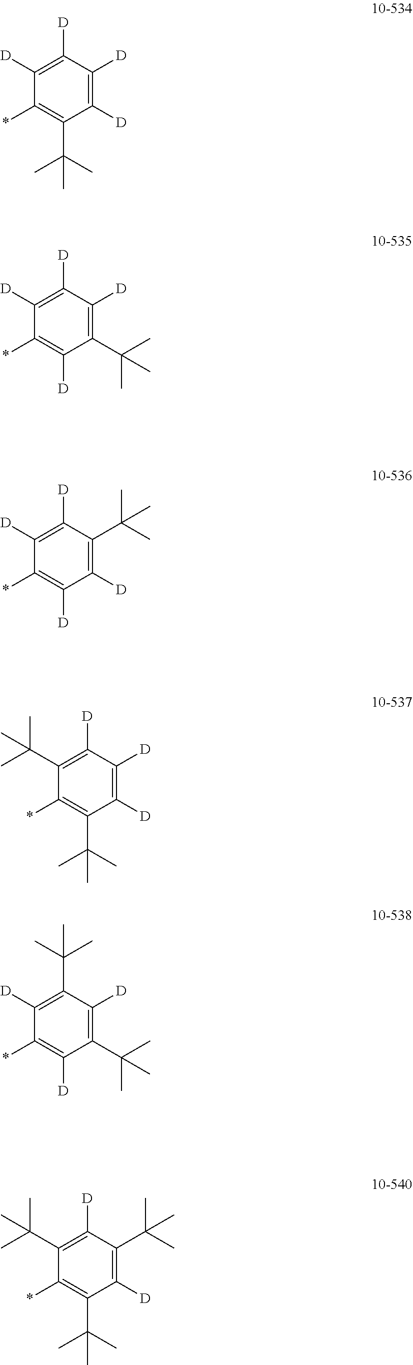

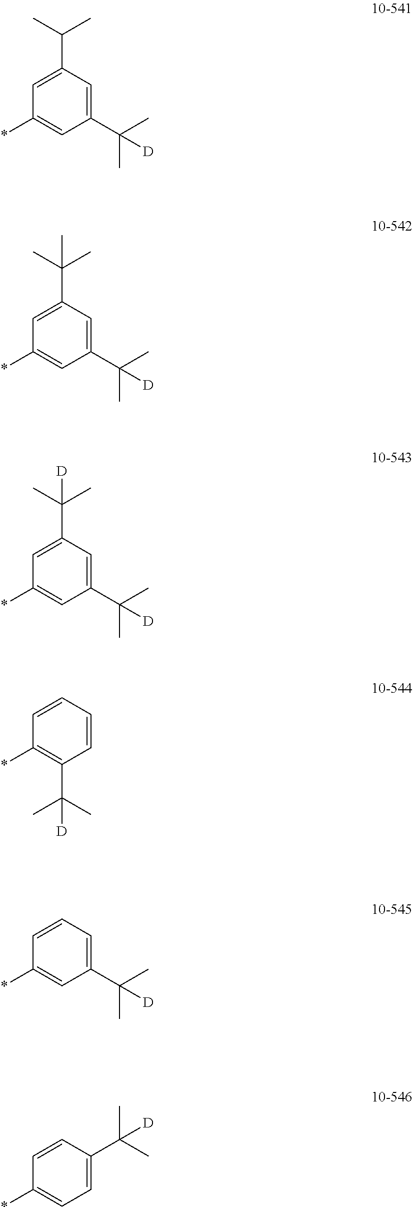 [SMILES: *c1cc(C(C)C)cc(C([2H])(C)C)c1 ; *c1cc(C([2H])(C)C)cc(C(C)(C)C)c1 ; *c1cc(C([2H])(C)C)cc(C([2H])(C)C)c1 ; *c1ccccc1C([2H])(C)C ; *c1cccc(C([2H])(C)C)c1 ; *c1ccc(C([2H])(C)C)cc1]

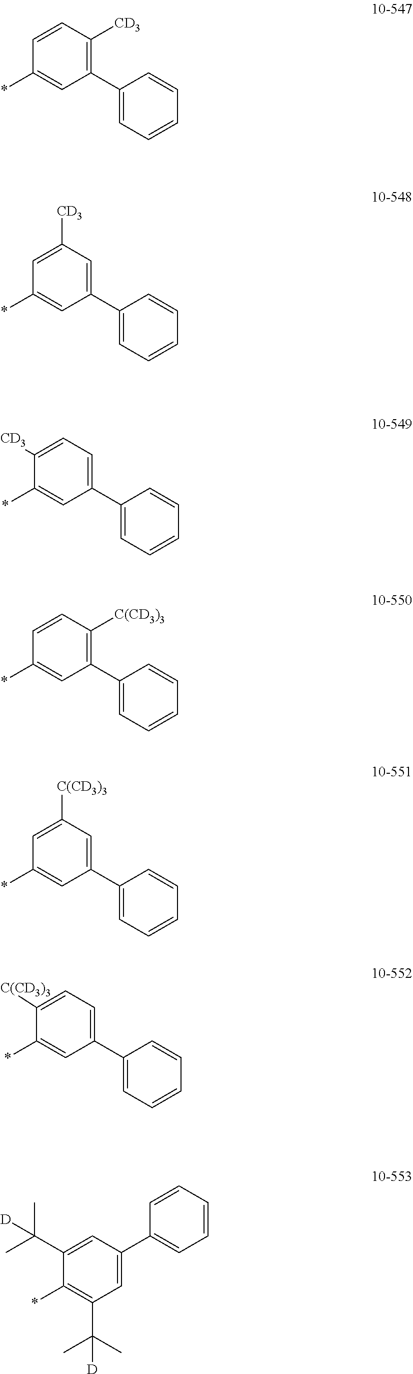

The “group represented by one of Formulae 10-1 to 10-129 in which at least one hydrogen is substituted with —F” and the “group represented by one of Formulae 10-201 to 10-350 in which at least one hydrogen is substituted with —F” may each be, for example, a group represented by one of Formulae 10-601 to 10-617:

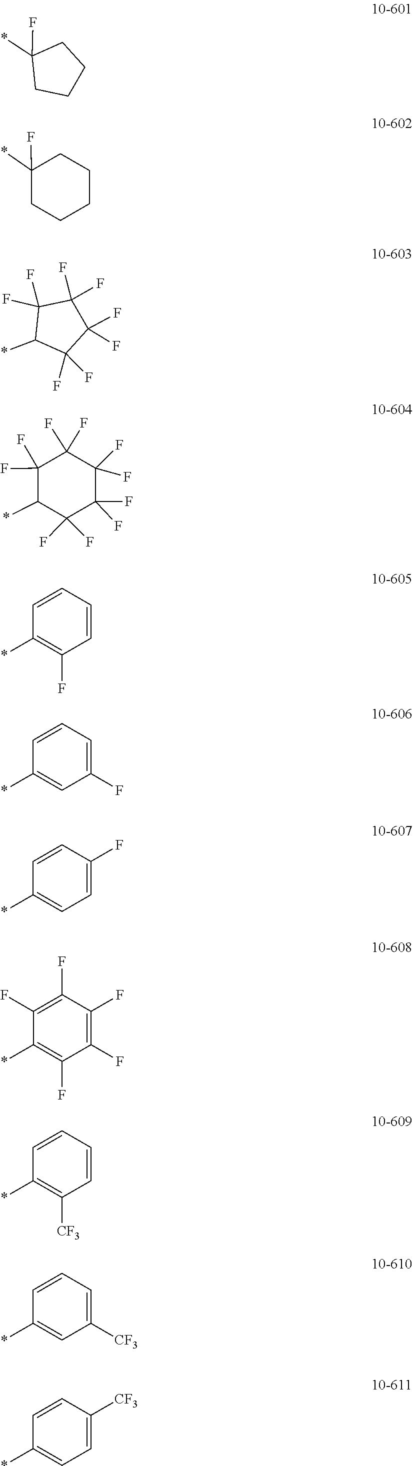

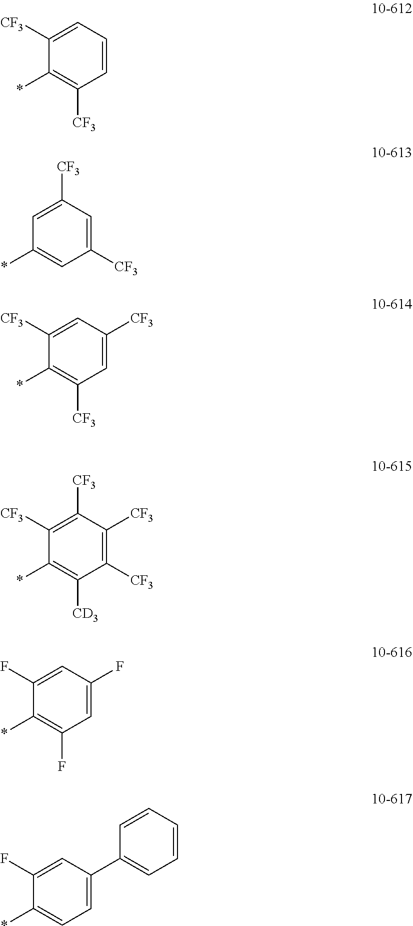 [SMILES: *c1c(C(F)(F)F)cccc1C(F)(F)F ; *c1cc(C(F)(F)F)cc(C(F)(F)F)c1 ; *c1c(C(F)(F)F)cc(C(F)(F)F)cc1C(F)(F)F ; *c1c(C([2H])([2H])[2H])c(C(F)(F)F)c(C(F)(F)F)c(C(F)(F)F)c1C(F)(F)F ; *c1c(F)cc(F)cc1F ; *c1ccc(-c2ccccc2)cc1F]

In Formulae 1, 2-1, and 2-2, c1 to c4 indicate the number of R₁(s) to the number of R₄(s), respectively; a1 to a4 indicate the number of groups represented by *-[(L₁)_{b1}-(R₁)_{c1}], the number of groups represented by *-[(L₂)_{b2}-(R₂)_{c2}], the number of groups represented by *-[(L₃)_{b3}-(R₃)_{c3}], and the number of groups represented by *-[(L₄)_{b4}-(R₄)_{c4}], respectively; e1 to e4 indicate the number of Z₁(s) to the number of Z₄(s), respectively; and d1 to d4 indicate the number of groups represented by *—[W₁—(Z₁)ₑ₁], the number of groups represented by *—[W₂—(Z₂)ₑ₂], the number of groups represented by *—[W₃—(Z₃)ₑ₃], and the number of groups represented by *—[W₄—(Z₄)ₑ₄], respectively, and c1 to c4, a1 to a4, e1 to e4, and d1 to d4 may each independently be an integer from 0 to 20. When c1 is 2 or more, two or more of R₁(s) may be identical to or different from each other, when c2 is 2 or more, two or more of R₂(s) may be identical to or different from each other, when c3 is 2 or more, two or more of R₃(s) may be identical to or different from each other, when c4 is 2 or more, two or more of R₄(s) may be identical to or different from each other, when a1 is 2 or more, two or more of groups represented by *-[(L₁)_{b1}-(R₁)_{c1}] may be identical to or different from each other, when a2 is 2 or more, two or more of groups represented by *-[(L₂)_{b2}-(R₂)_{c2}] may be identical to or different from each other, when a3 is 2 or more, two or more of groups represented by *-[(L₃)_{b3}-(R₃)_{c3}] may be identical to or different from each other, when a4 is 2 or more, two or more of groups represented by *-[(L₄)_{b4}-(R₁)_{c4}] may be identical to or different from each other, when e1 is 2 or more, two or more of Z₁(s) may be identical to or different from each other, when e2 is 2 or more, two or more of Z₂(s) may be identical to or different from each other, when e3 is 2 or more, two or more of Z₃(s) may be identical to or different from each other, when e4 is 2 or more, two or more of Z₄(s) may be identical to or different from each other, when d1 is 2 or more, two or more of groups represented by *—[W₁—(Z₁)ₑ₁] may be identical to or different from each other, when d2 is 2 or more, two or more of groups represented by *—[W₂—(Z₂)ₑ₂] may be identical to or different from each other, when d3 is 2 or more, two or more of groups represented by *—[W₃—(Z₃)e3] may be identical to or different from each other, and when d4 is 2 or more, two or more of groups represented by *—[W₄—(Z₄)ₑ₁] may be identical to or different from each other. For example, in Formulae 1, 2-1, and 2-2, c1 to c4, a1 to a4, e1 to e4, and d1 to d4 may each independently be 0, 1, 2, or 3.

In one or more embodiments, in Formula 2-1, a case where Y₁ is N, ring A₁ is a pyridine group, Y₂ is C, ring A₂ is a benzene group, and d1 and d2 are each 0 may be excluded.

In Formulae 1, 2-1, and 2-2, at least one of i) two or more of a plurality of R₁(s), ii) two or more of a plurality of R₂(s), iii) two or more of a plurality of R₃(s), iv) two or more of a plurality of R₄(s), v) R₅ₐ and R_{5b}, vi) two or more of a plurality of Z₁(s), vii) two or more of a plurality of Z₂(s), viii) two or more of a plurality of Z₃(s), ix) two or more of a plurality of Z₄(s), x) two or more of R₁ to R₄, R₅ₐ, and R_{5b}, and xi) two or more of Z₁ to Z₄ may optionally be bonded to each other to form a C₅-C₃₀ carbocyclic group unsubstituted or substituted with at least one R₁₀ₐ or a C₁-C₃₀ heterocyclic group unsubstituted or substituted with at least one R₁₀ₐ.

R₁₀ₐ is as described in connection with R₁.

* and *′ in the present specification each indicate a binding site to a neighboring atom, unless otherwise stated.

In one or more embodiments, in Formula 1, n1 may not be 0, n4 may be 0, and a group represented by

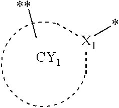

may be a group represented by one of Formulae CY1(1) to CY1(23):

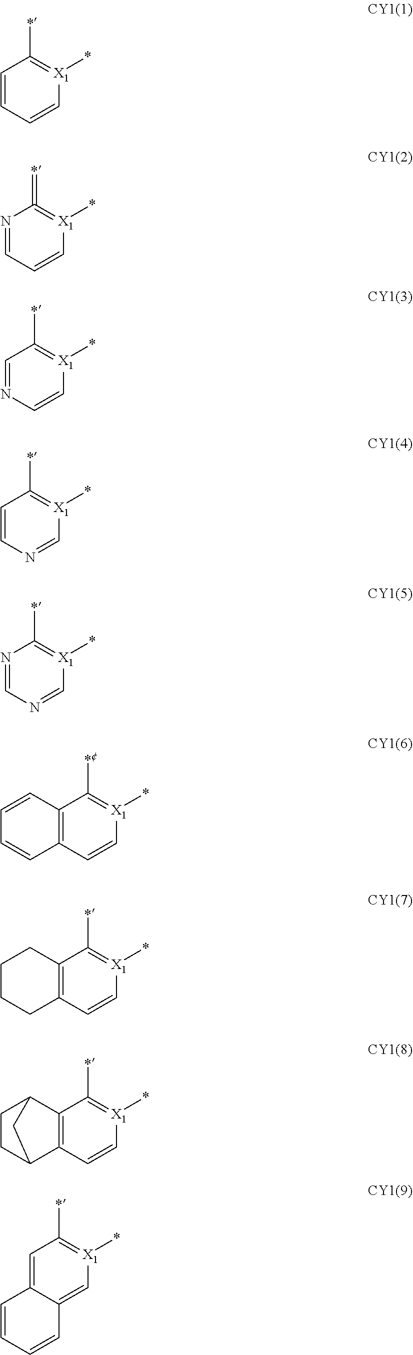

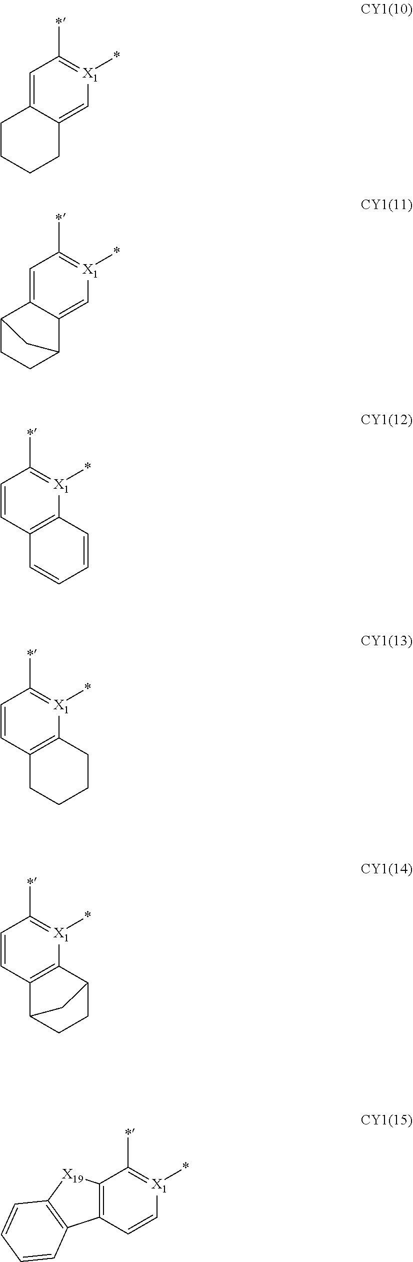

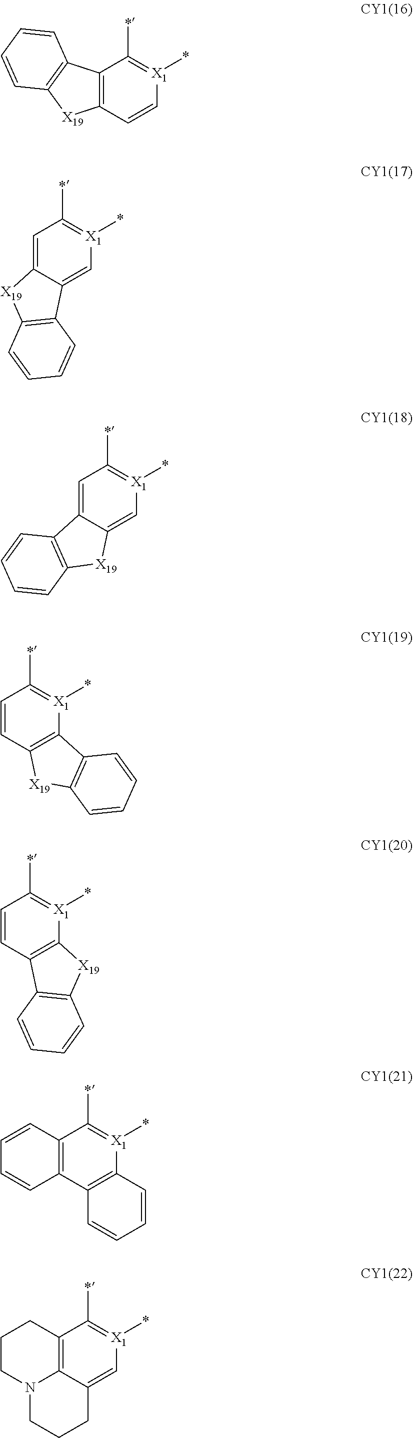

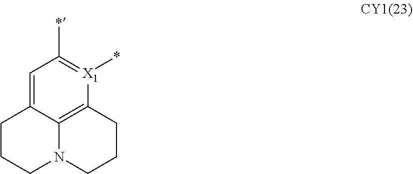

wherein, in Formulae CY1(1) to CY1(23),
X₁ is as described in the present specification,
X₁₉ may be O, S, Se, N(R₁₉ₐ), C(R₁₉ₐ)(R_{19b}), or Si(R₁₉ₐ)(R_{19b}),
R₁₉ₐ and R_{19b} are respectively as those described in connection with R₁,
* indicates a binding site to X₅ or M₁ in Formula 1, and
*′ indicates a binding site to T₁₁ in Formula 1.

In one or more embodiments, in Formula 1, n1 may be 1, n4 may be 0, and a group represented by

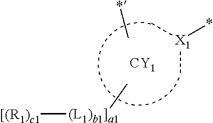

may be a group represented by one of Formulae CY1-1 to CY1-18:

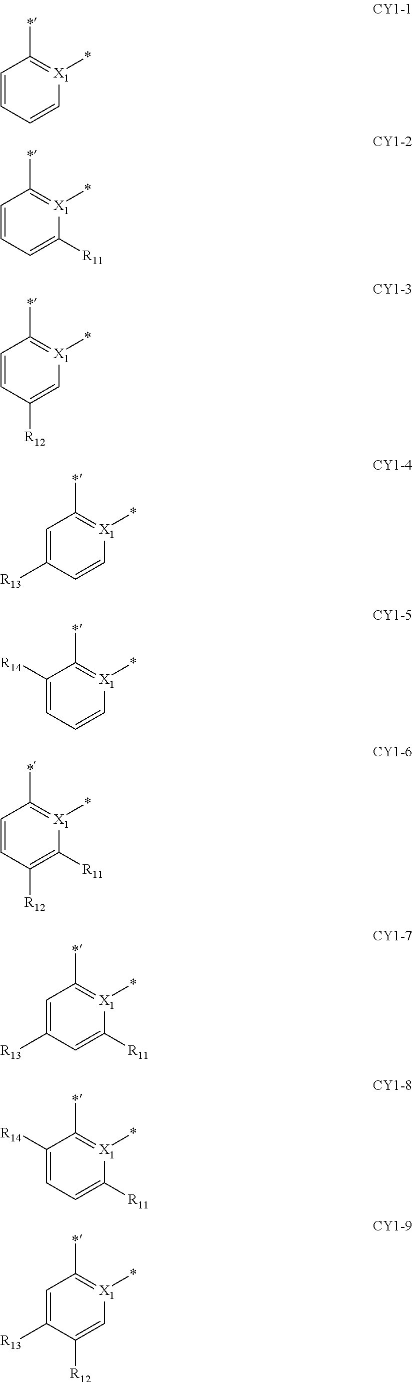

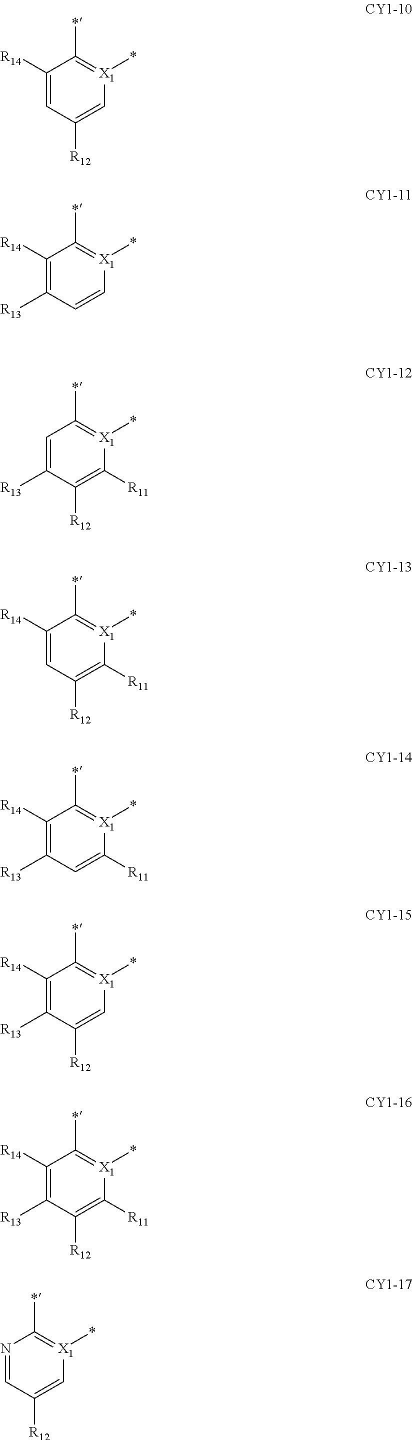

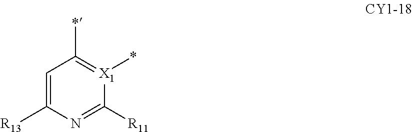

wherein, in Formulae CY1-1 to CY1-18,
X₁ is as described in the present specification,
R₁₁ to R₁₄ are each as described in connection with R₁, wherein R₁₁ to R₁₄ are each not hydrogen,
* indicates a binding site to X₅ or M₁ in Formula 1, and
*′ indicates a binding site to T₁₁ in Formula 1.

In one or more embodiments, in Formula 1, n1 and n2 may each be 1, and ring CY₂ may be a group represented by Formula CY2A or CY2B:

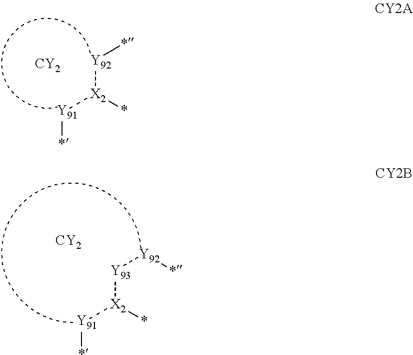

wherein, in Formulae CY2A and CY2B,
X₂ and ring CY₂ are respectively as those described in the present specification,
Y₉₁ and Y₉₂ may each independently be N, C, or Si, and Y₉₃ may be O, S, N, C, or Si,
in Formulae CY2A and CY2B, a bond between X₂ and Y₉₁, a bond between X₂ and Y₉₂, a bond between X₂ and Y₉₃, and a bond between Y₉₂ and Y₉₃ may each be a chemical bond,
*′ indicates a binding site to T₁₁ in Formula 1,
*indicates a binding site to M₁ in Formula 1, and
*″ indicates a binding site to T₁₂ in Formula 1.

In one or more embodiments, in Formula 1, each of n1 and n2 may not be 0, and a group represented by

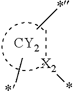

may be a group represented by one of Formulae CY2(1) to CY2(21):

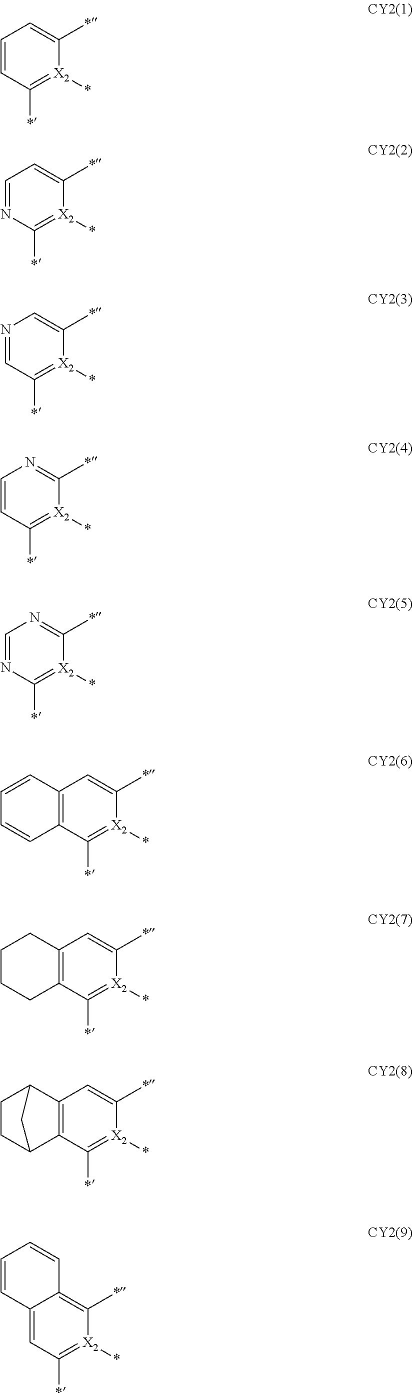

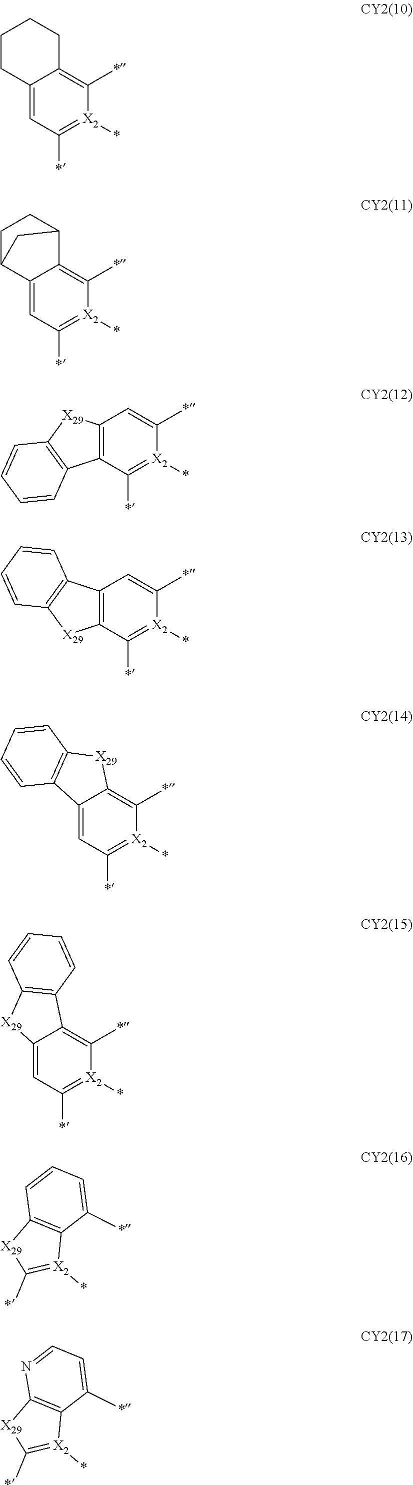

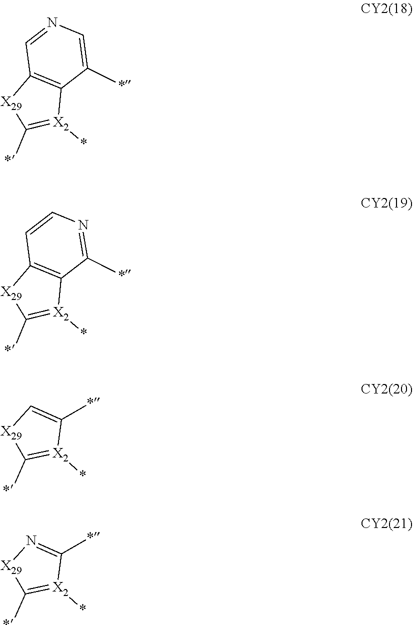

wherein, in Formulae CY2(1) to CY2(21),
X₂ is as described in the present specification,
X₂₉ may be O, S, N-[(L₂)_{b2}-(R₂)_{c2}], C(R₂₉ₐ)(R_{29b}), or Si(R₂₉ₐ)(R_{29b}),
L₂, b2, R₂, and c2 are respectively as those described in the present specification,
R₂₉ₐ and R_{29b} are each as described in connection with R₂,
*′ indicates a binding site to T₁₁ in Formula 1,
* indicates a binding site to X₆ or M₁ in Formula 1, and
*″ indicates a binding site to T₁₂ in Formula 1.

In one or more embodiments, in Formula 1, each of n1 and n2 may be 1, and a group represented by

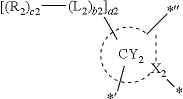

may be a group represented by one of Formulae CY2-1 to CY2-16:

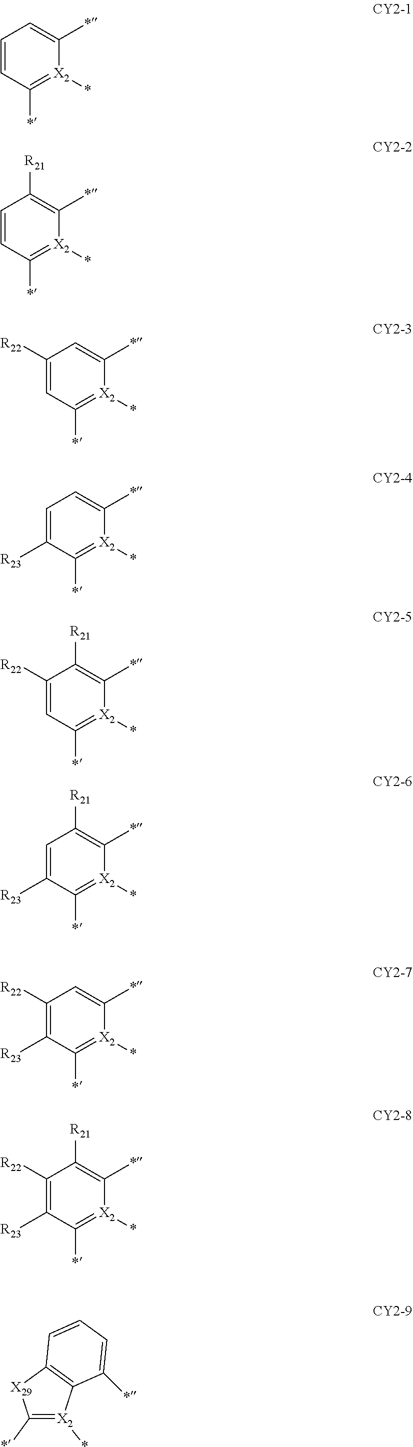

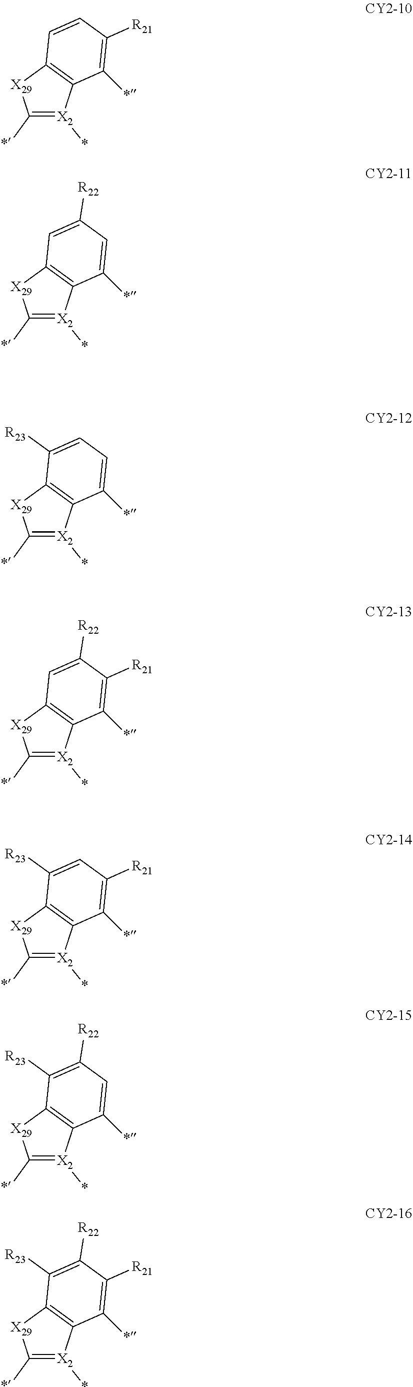

wherein, in Formulae CY2-1 to CY2-16,
X₂ is as described in the present specification,
X₂₉ may be O, S, N-[(L₂)_{b2}-(R₂)_{c2}], C(R₂₉ₐ)(R_{29b}), or Si(R₂₉ₐ)(R_{29b}),
L₂, b2, R₂, and c2 are respectively as those described in the present specification,
R₂₁ to R₂₃, R₂₉ₐ, and R_{29b} are each as described in connection with R₂, wherein R₂₁ to R₂₃ are each not hydrogen,
*′ indicates a binding site to T₁₁ in Formula 1,
* indicates a binding site to X₆ or M₁ in Formula 1, and
*″ indicates a binding site to T₁₂ in Formula 1.

In one or more embodiments, in Formula 1,
each of n1 and n2 may be 1,
a group represented by

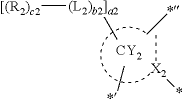

may be a group represented by one of Formulae CY2-9 to CY2-16,
X₂₉ in Formulae CY2-9 to CY2-16 may be N-[(L₂)_{b2}-(R₂)_{c2}],
L₂ may be a benzene group unsubstituted or substituted with at least one R₁₀ₐ,
b2 may be 1 or 2,
c2 may be 1 or 2,
when c2 is 1, R₂ may be a phenyl group unsubstituted or substituted with at least one of deuterium, a C₁-C₂₀ alkyl group, a phenyl group, a deuterated phenyl group, a (C₁-C₂₀alkyl)phenyl group, or a combination thereof; and when c2 is 2, a) one of two R₂(s) may be a phenyl group unsubstituted or substituted with deuterium, a C₁-C₂₀ alkyl group, a phenyl group, a deuterated phenyl group, a (C₁-C₂₀ alkyl)phenyl group, or a combination thereof, and b) the other R₂ may be a C₄-C₂₀ alkyl group or a deuterated C₁-C₂₀ alkyl group, each unsubstituted or substituted with at least one C₃-C₁₀ cycloalkyl group.

In one or more embodiments, in Formula 1, each of n2 and n3 may not be 0, and a group represented by

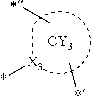

may be a group represented by one of Formulae CY3(1) to CY3(15):

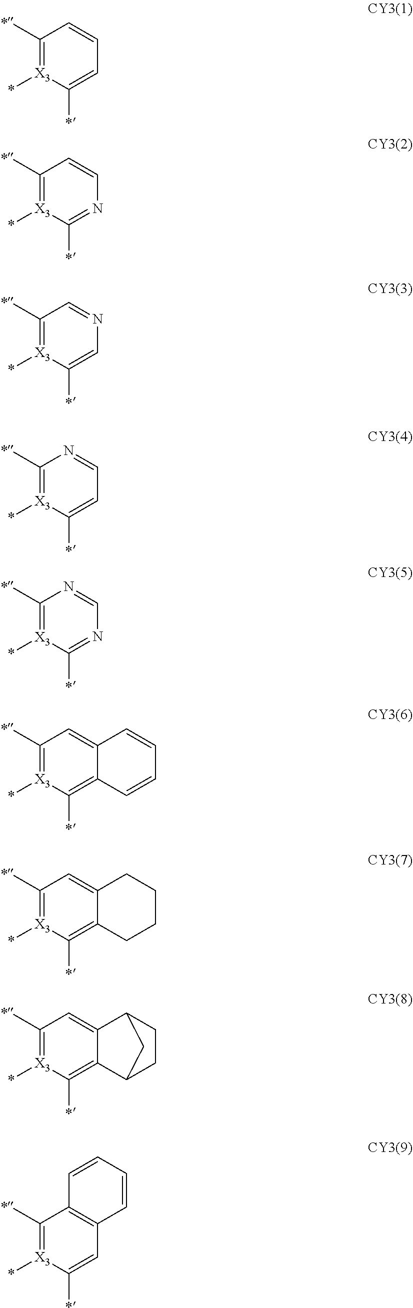

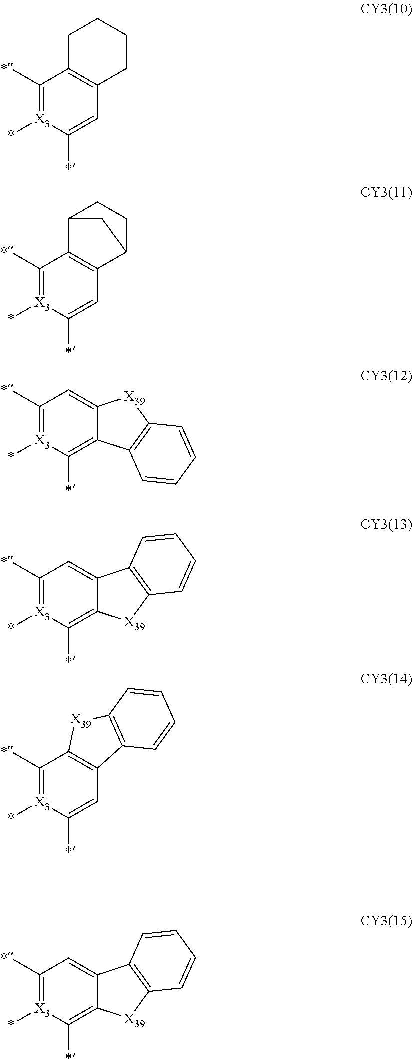

wherein, in Formulae CY3(1) to CY3(15),
X₃ is as described in the present specification,
X₃₉ may be O, S, N(Z₃₉ₐ), C(R₃₉ₐ)(R_{39b}), or Si(R₃₉ₐ)(R_{39b}),
R₃₉ₐ and R_{39b} are each as described in connection with R₃,
*″ indicates a binding site to T₁₂ in Formula 1,
* indicates a binding site to X₇ or M₁ in Formula 1, and
*′ indicates a binding site to T₁₃ in Formula 1.

In one or more embodiments, in Formula 1, each of n2 and n3 may be 1, and a group represented by

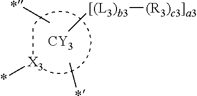

may be a group represented by one of Formulae CY3-1 to CY3-13:

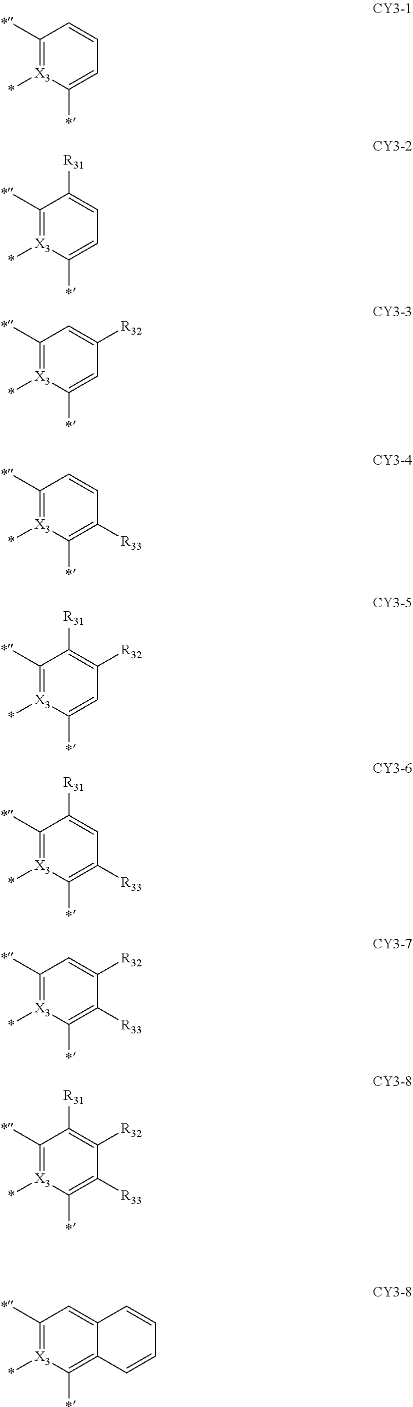

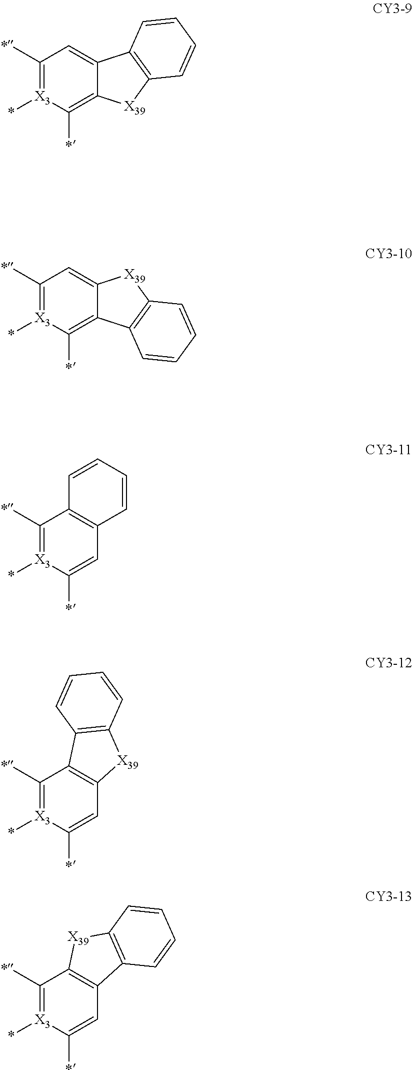

wherein, in Formulae CY3-1 to CY3-31,
X₃ is as described in the present specification,
X₃₉ may be O, S, N-[(L₃)_{b3}-(R₃)_{c3}], C(R₃₉ₐ)(R_{39b}), or Si(R₃₉ₐ)(R_{39b}),
L₃, b3, R₃, and c3 are respectively as those described in the present specification,
R₃₁ to R₃₃, R₃₉ₐ, and R_{39b} are each as described in connection with R₃, wherein R₃₁ to R₃₃ are each not hydrogen,
*″ indicates a binding site to T₁₂ in Formula 1,
* indicates a binding site to X₇ or M₁ in Formula 1, and
*′ indicates a binding site to T₁₃ in Formula 1.

In one or more embodiments, in Formula 1, n3 may not be 0, n4 may be 0, and a group represented by

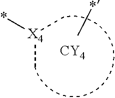

may be a group represented by one of Formulae CY4(1) to CY4(20):

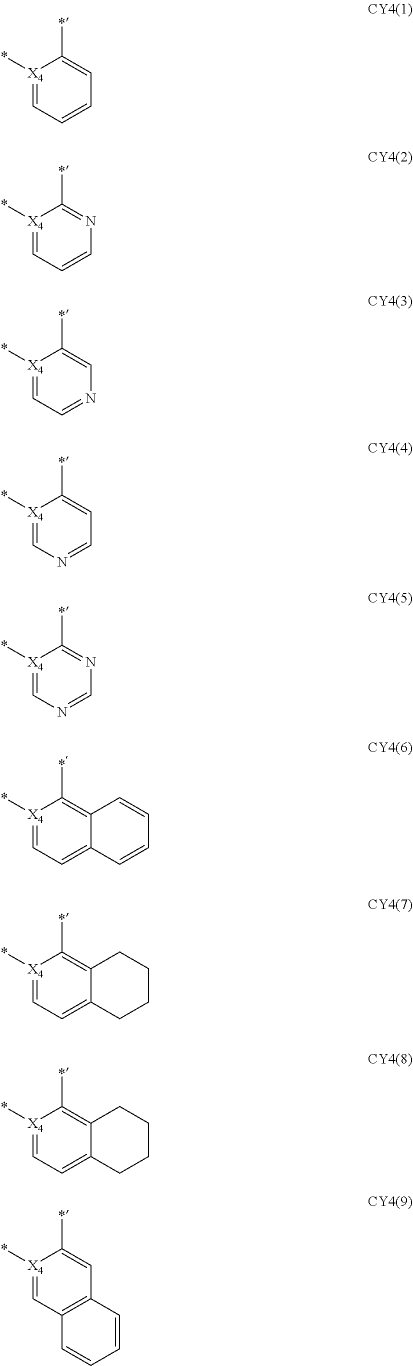

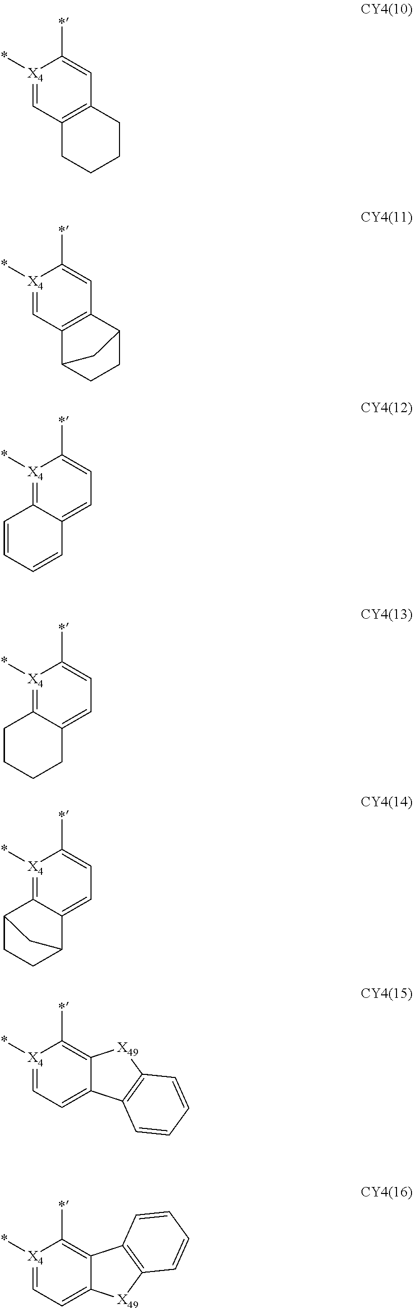

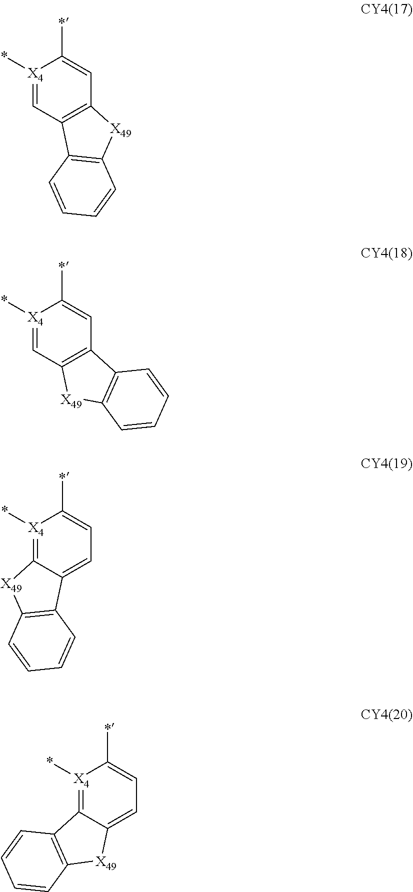

wherein, in Formulae CY4(1) to CY4(20),
X₄ is as described in the present specification,
X₄₉ may be O, S, N(R₄₉ₐ), C(R₄₉ₐ)(R_{49b}), or Si(R₄₉ₐ)(R_{49b}),
R₄₉ₐ and R_{49b} are each as described in connection with R₄,
*′ indicates a binding site to T₁₃ in Formula 1, and
* indicates a binding site to X₈ or M₁ in Formula 1.

In one or more embodiments, in Formula 1, n3 may be 1, n4 may be 0, and a group represented by

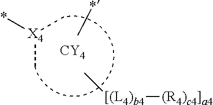

may be a group represented by one of Formulae CY4-1 to CY4-16:

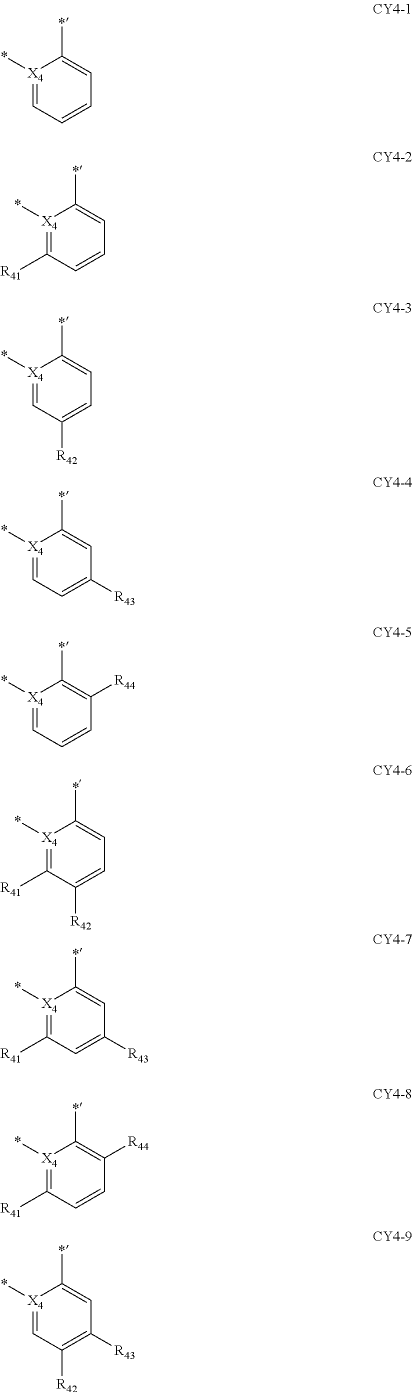

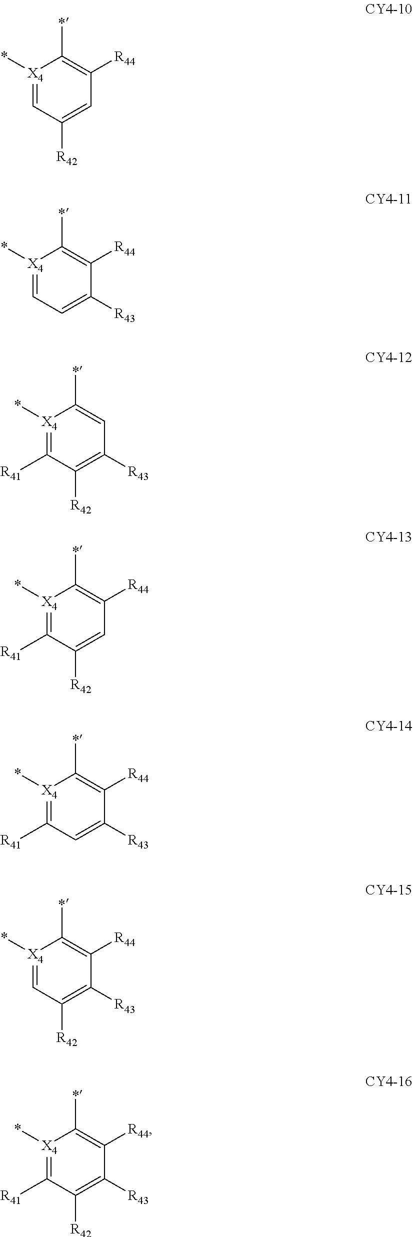

wherein, in Formulae CY4-1 to CY4-16,
X₄ is as described in the present specification,
R₄₁ to R₄₄ are each as described in connection with R₄, wherein R₄₁ to R₄₄ are each not hydrogen,
*′ indicates a binding site to T₁₃ in Formula 1, and
* indicates a binding site to X₈ or M₁ in Formula 1.

In one or more embodiments, the platinum-containing organometallic compound may be a compound represented by one of Formulae 1-1 to 1-3:

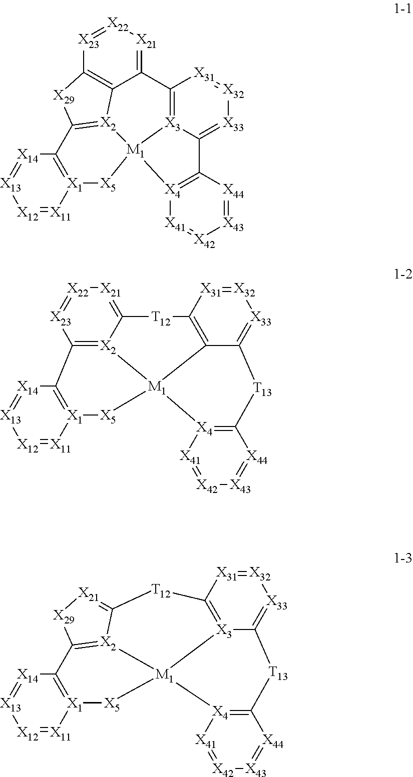

wherein, in Formulae 1-1 to 1-3,
M₁, X₁ to X₅, T₁₂, and T₁₃ are respectively as those described in the present specification,
X₁₁ may be N or C(R₁₁), X₁₂ may be N or C(R₁₂), X₁₃ may be N or C(R₁₃), and X₁₄ may be N or C(R₁₄),
R₁₁ to R₁₄ are each as described in connection with R₁,
two or more of R₁₁ to R₁₄ may optionally be bonded to each other to form a C₅-C₃₀ carbocyclic group unsubstituted or substituted with at least one R₁₀ₐ or a C₁-C₃₀ heterocyclic group unsubstituted or substituted with at least one R₁₀ₐ,
X₂₁ may be N or C(R₂₁), X₂₂ may be N or C(R₂₂), and X₂₃ may be N or C(R₂₃),
X₂₉ may be O, S, N-[(L₂)_{b2}-(R₂)_{c2}], C(R₂₉ₐ)(R_{29b}), or Si(R₂₉ₐ)(R_{29b}),
L₂, b2, R₂, and c2 may each be as described herein,
R₂₁ to R₂₃, R₂₉ₐ, and R_{29b} are each as described in connection with R₂,
two or more of R₂₁ to R₂₃ may optionally be bonded to each other to form a C₅-C₃₀ carbocyclic group unsubstituted or substituted with at least one R₁₀ₐ or a C₁-C₃₀ heterocyclic group unsubstituted or substituted with at least one R₁₀ₐ,
X₃₁ may be N or C(R₃₁), X₃₂ may be N or C(R₃₂), and X₃₃ may be N or C(R₃₃),
R₃₁ to R₃₃ are each as described in connection with R₃,
two or more of R₃₁ to R₃₃ may optionally be bonded to each other to form a C₅-C₃₀ carbocyclic group unsubstituted or substituted with at least one R₁₀ₐ or a C₁-C₃₀ heterocyclic group unsubstituted or substituted with at least one R₁₀ₐ,
X₄₁ may be N or C(R₄₁), X₄₂ may be N or C(R₄₂), X₄₃ may be N or C(R₄₃), and X₄₄ may be N or C(R₄₄),
R₄₁ to R₄₄ are each as described in connection with R₄, and
two or more of R₄₁ to R₄₄ may optionally be bonded to each other to form a C₅-C₃₀ carbocyclic group unsubstituted or substituted with at least one R₁₀ₐ or a C₁-C₃₀ heterocyclic group unsubstituted or substituted with at least one R₁₀ₐ.

In one or more embodiments,
Y₁ in Formula 2-1 may be N, and
a group represented by

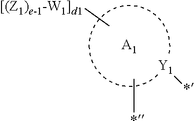

in Formula 2-1 may be a group represented by one of Formulae A1-1 to A1-3:

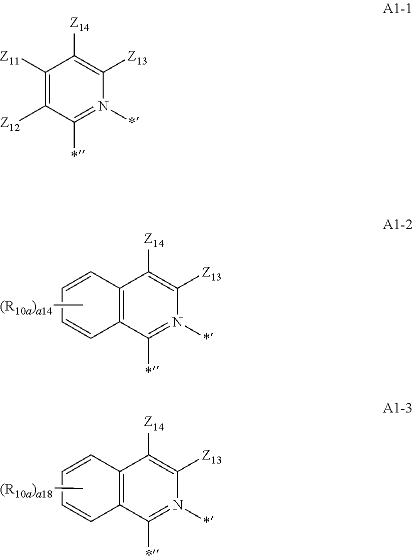

wherein, in Formulae A1-1 to A1-3,
Z₁₁ to Z₁₄ are each as described in connection with Z₁,
R₁₀ₐ is as described in the present specification,
a14 may be an integer from 0 to 4,
a18 may be an integer from 0 to 8,
*′ indicates a binding site to M₂ in Formula 2, and
*″ indicates a binding site to ring A₂.

For example, Z₁₄ in Formulae A1-1 to A1-3 may be a deuterated C₁-C₂₀ alkyl group, —Si(Q₃)(Q₄)(Q₅), or —Ge(Q₃)(Q₄)(Q₅).

In one or more embodiments,
Y₃ in Formula 2-2 may be N, and
a group represented by

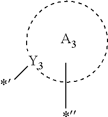

in Formula 2-2 may be a group represented by one of Formulae NR1 to NR48:

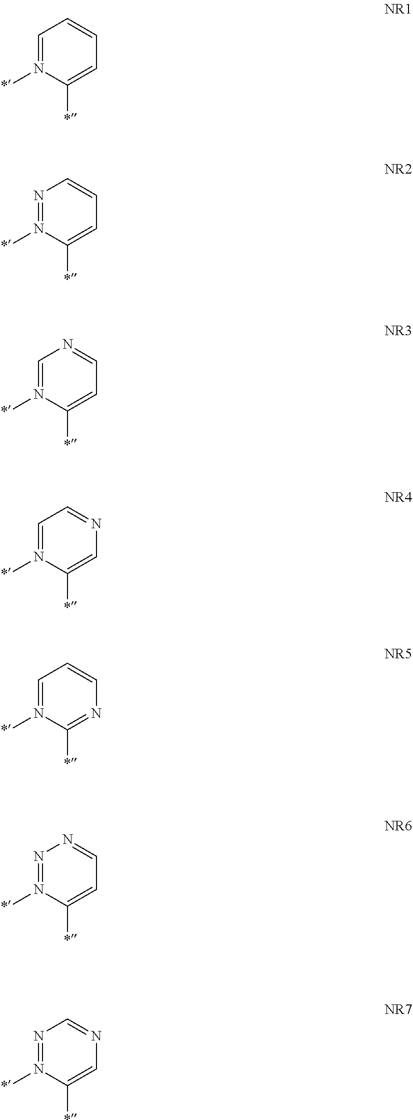

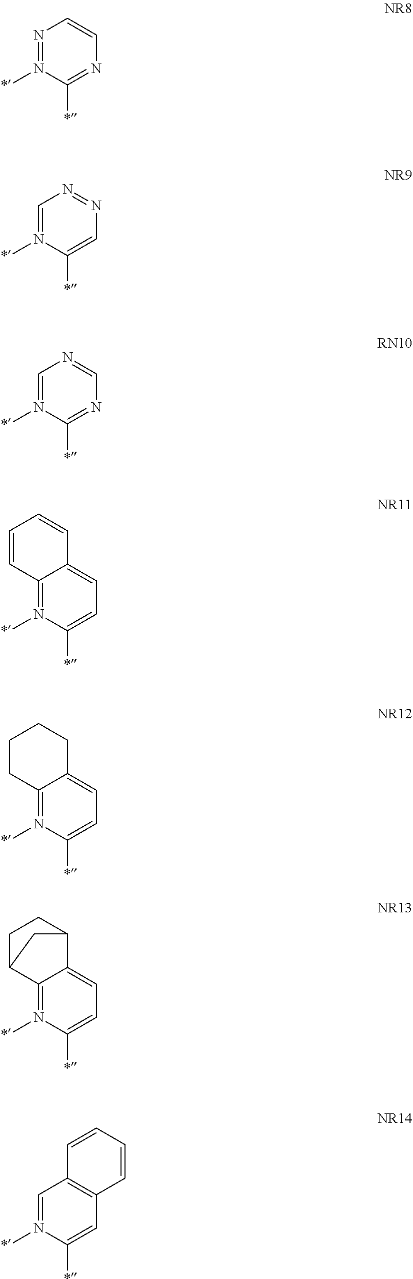

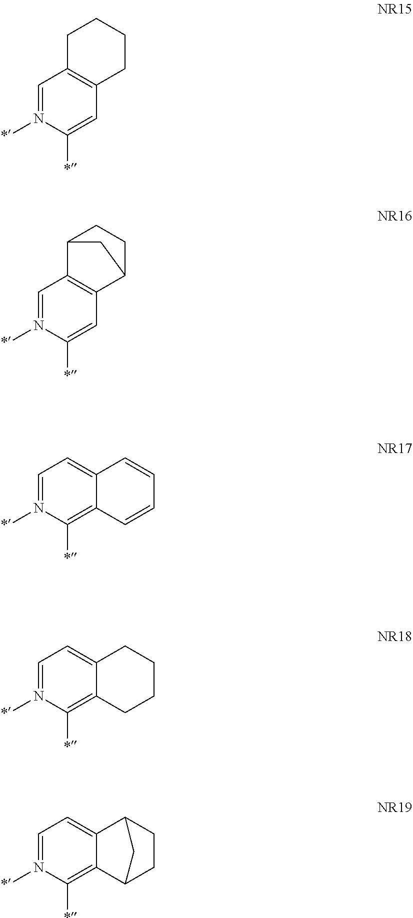

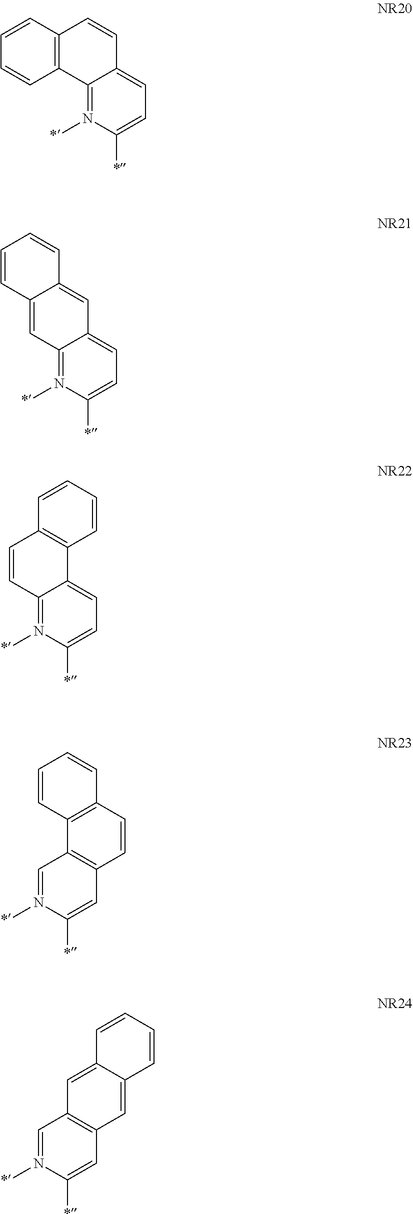

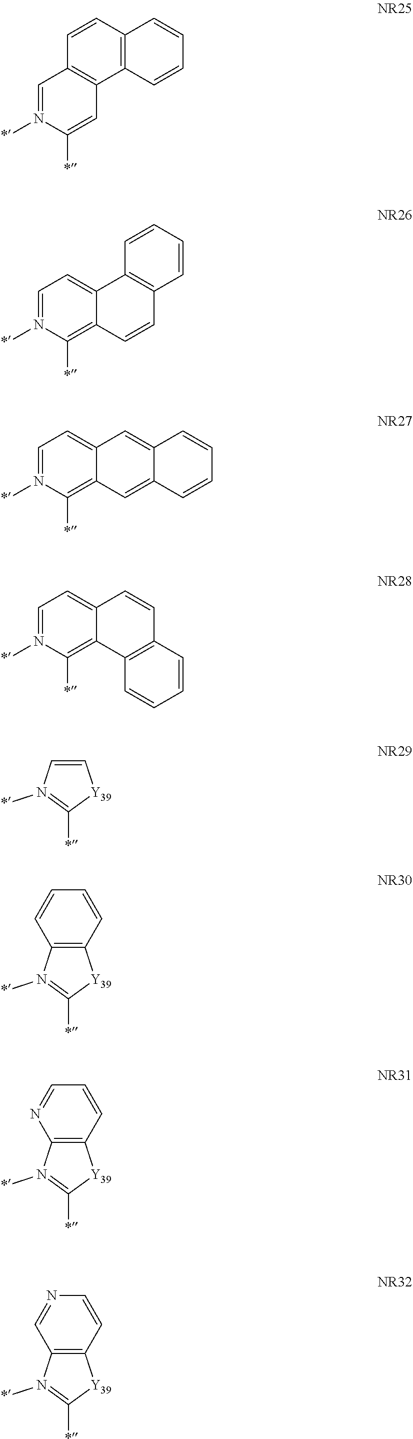

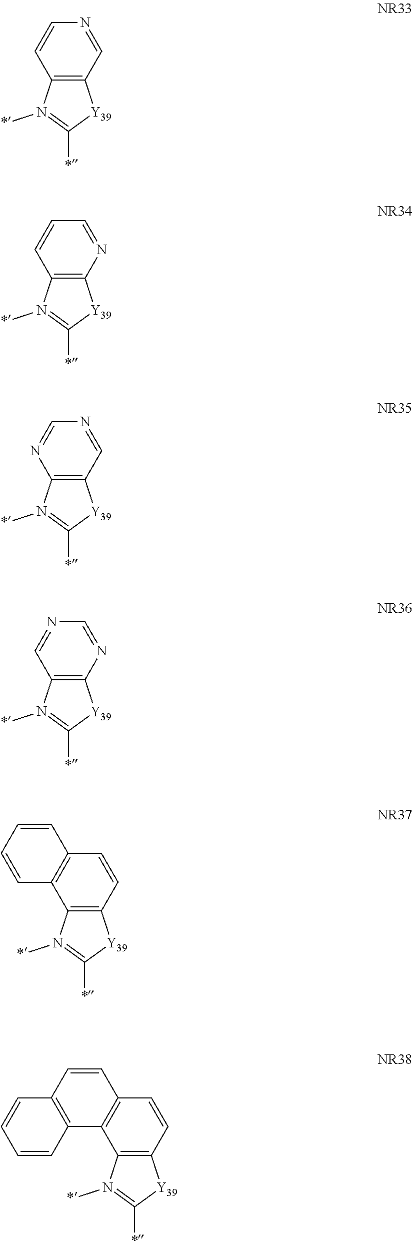

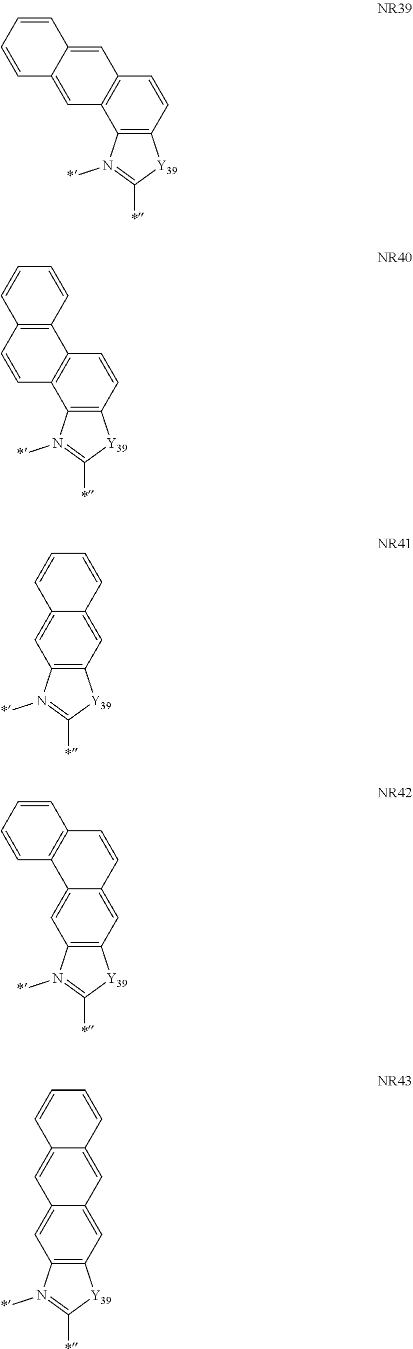

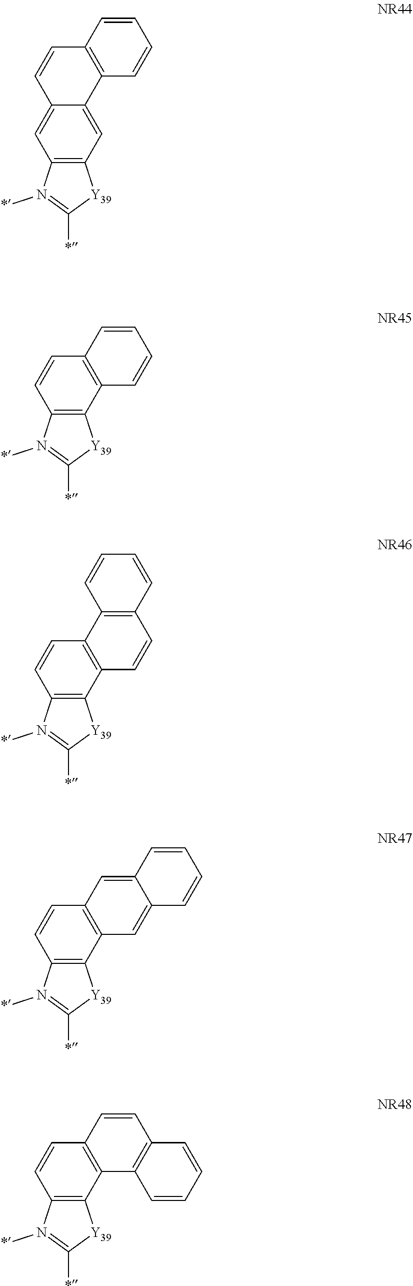

wherein, in Formulae NR1 to NR48,
Y₃₉ may be O, S, Se, N—[W₃—(Z₃)ₑ₃], C(Z₃₉ₐ)(Z_{39b}), or Si(Z₃₉ₐ)(Z_{39b}), W₃, Z₃, and e3 are each as described in the present specification, and Z₃₉ₐ and Z_{39b} are each as described in connection with Z₃ in the present specification,
*′ indicates a binding site to M₂ in Formula 2, and
*″ indicates a binding site to ring A₄.

In one or more embodiments,
Y₂ and Y₄ in Formulae 2-1 and 2-2 may each be C, and
a group represented by

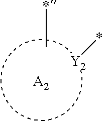

in Formula 2-1, and a group represented by

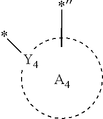

in Formula 2-2 may each independently be a group represented by one of Formulae CR1 to CR29:

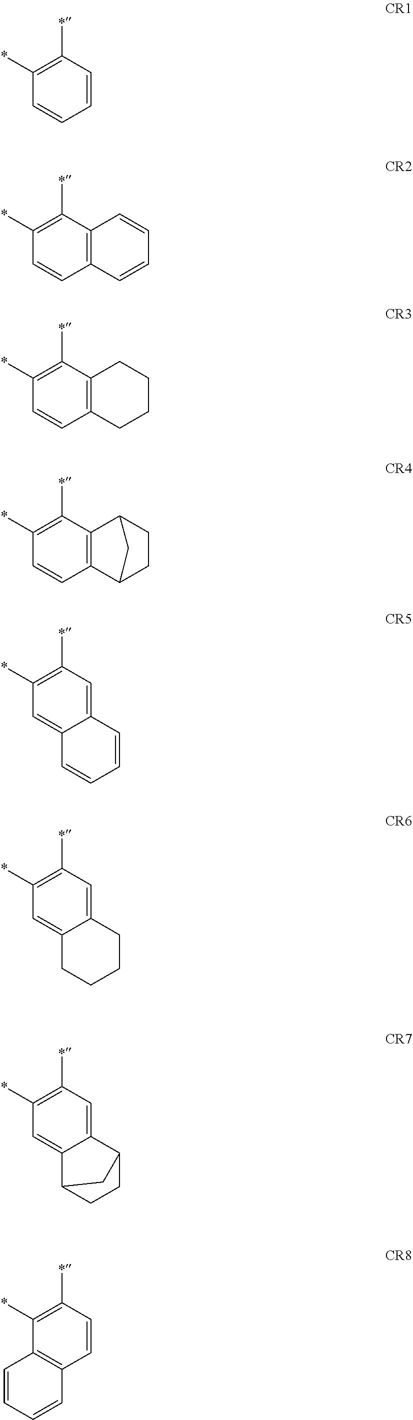

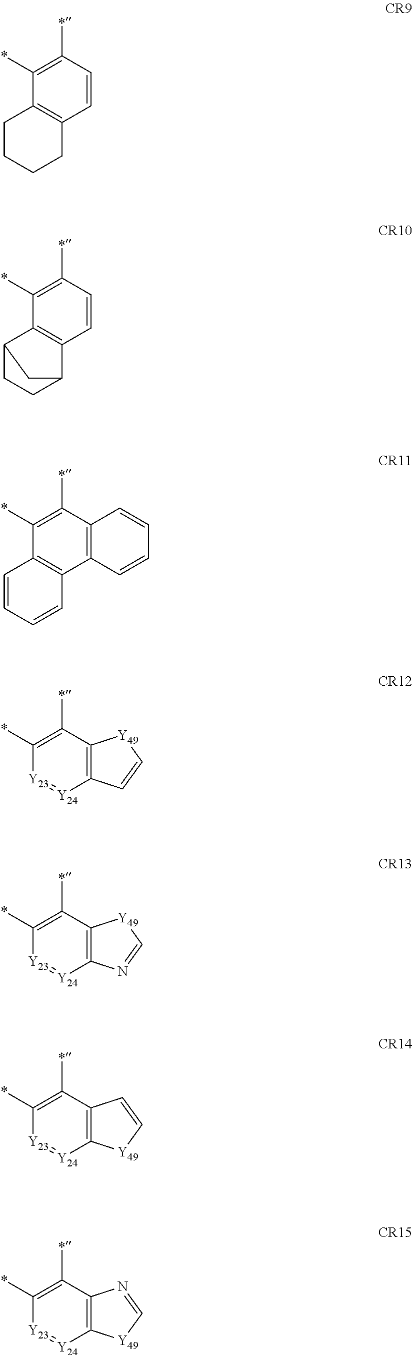

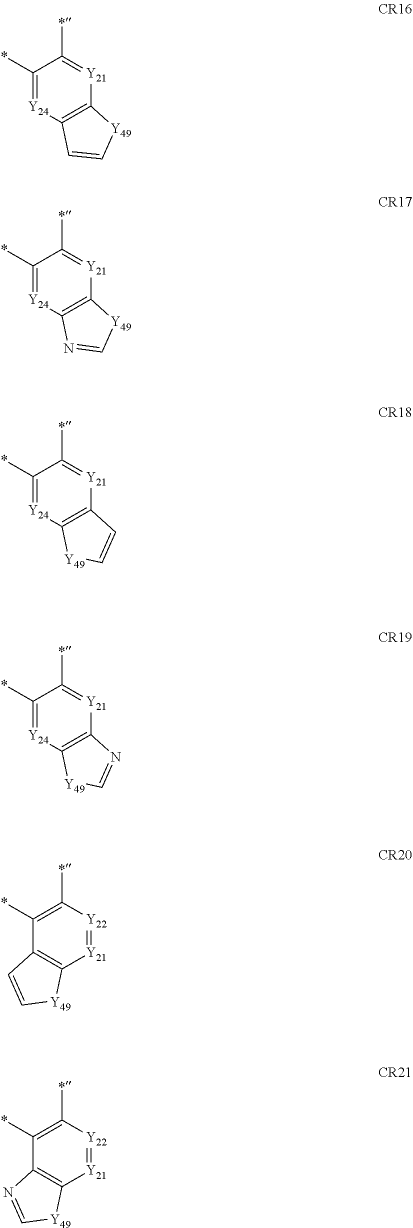

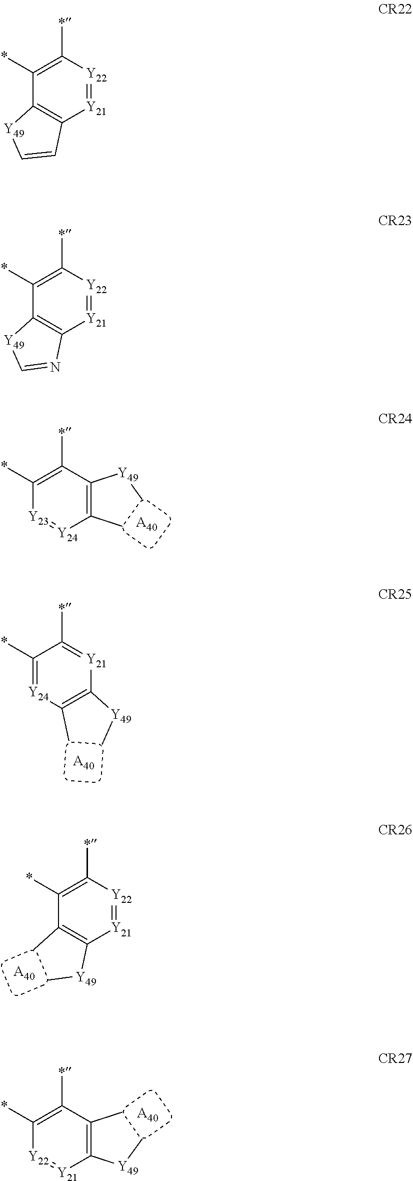

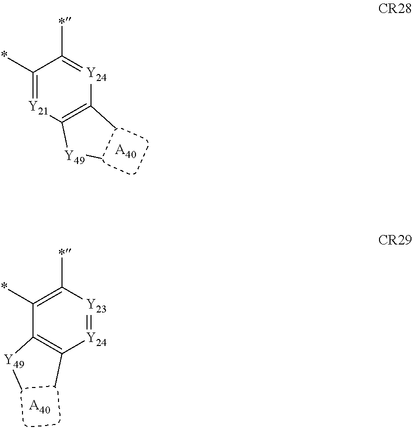

wherein, in Formulae CR1 to CR29,
Y₄₉ may be 0, S, Se, N—[W₂—(Z₂)ₑ₂], N—[W₄—(Z₄)ₑ₄], C(Z₂₉ₐ)(Z_{29b}), C(Z₄₉ₐ)(Z_{49b}), Si(Z₂₉ₐ)(Z_{29b}), or Si(Z₄₉ₐ)(Z_{49b}),
W₂, W₄, Z₂, Z₄, e2, and e4 are each as described in the present specification, Z₂₉ₐ and Z_{29b} are each as described in connection with Z₂ in the present specification, and Z₄₉ₐ and Z_{49b} are each as described in connection with Z₄ in the present specification,
Y₂₁ to Y₂₄ may each independently be N or C,
ring A₄₀ may be a C₅-C₃₀ carbocyclic group or a C₁-C₃₀ heterocyclic group (for example, a benzene group, a naphthalene group, a phenanthrene group, a pyridine group, a pyrimidine group, a pyrazine group, a pyridazine group, a quinoline group, an isoquinoline group, a benzoquinoline group, a benzoisoquinoline group, a quinoxaline group, a benzoquinoxaline group, a quinazoline group, or a benzoquinazoline group),
   indicates a binding site to M₂ in Formula 2, and
*″ indicates a binding site to ring A₁ or ring A₃.

In one or more embodiments,
a group represented by

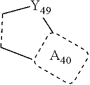

in Formulae CR24 to CR29 may be a group represented by one of Formulae CR(1) to CR(13):

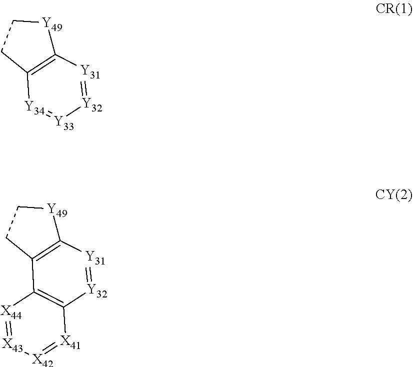

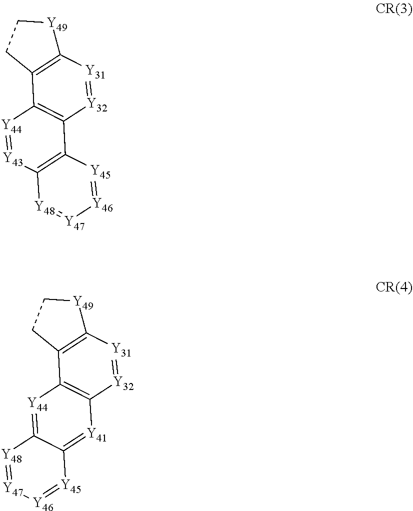

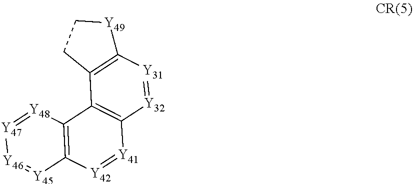

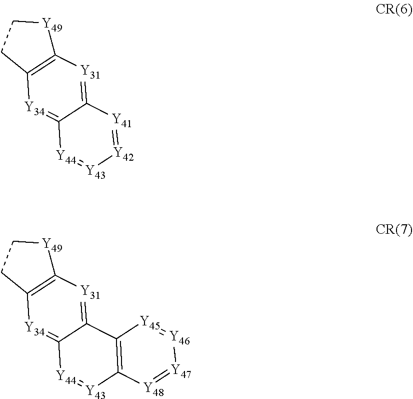

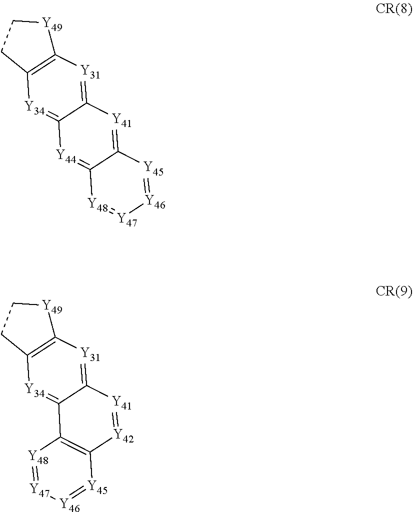

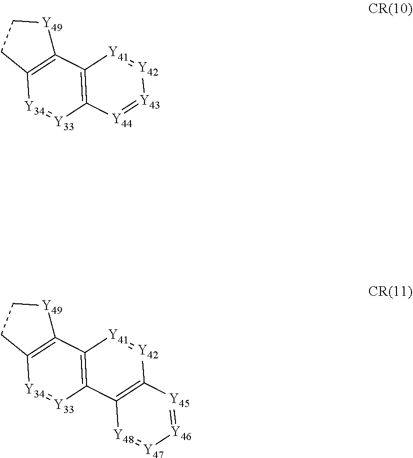

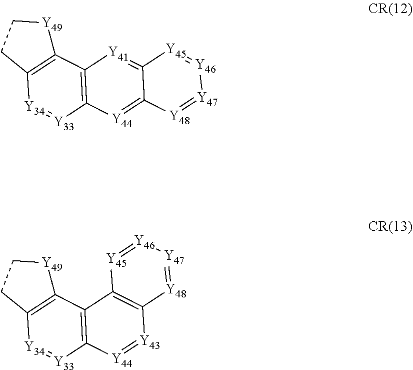

wherein, in Formulae CR(1) to CR(13),
Y₄₉ is as described in the present specification, and
Y₃₁ to Y₃₄ and Y₄₁ to Y₄₈ may each independently be C or N.

In one or more embodiments, the platinum-containing organometallic compound may include at least one deuterium.

In one or more embodiments, the iridium-containing organometallic compound may include at least one deuterium.

For example, the platinum-containing organometallic compound may be selected from compounds of [Group 1-1] to [Group 1-4]:

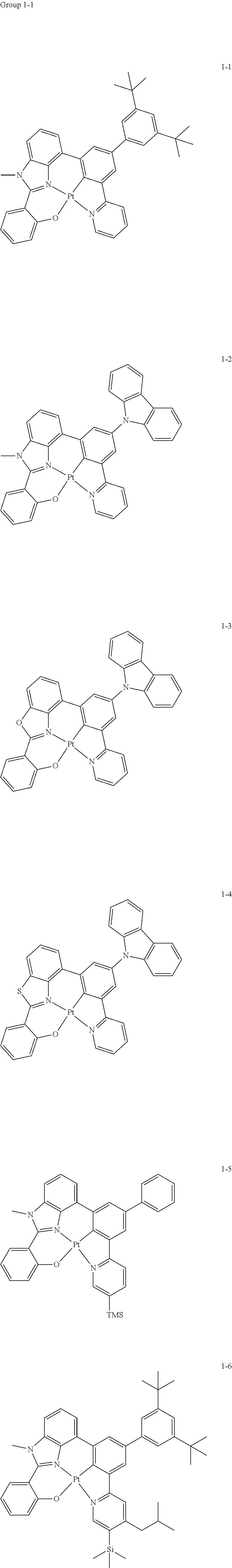

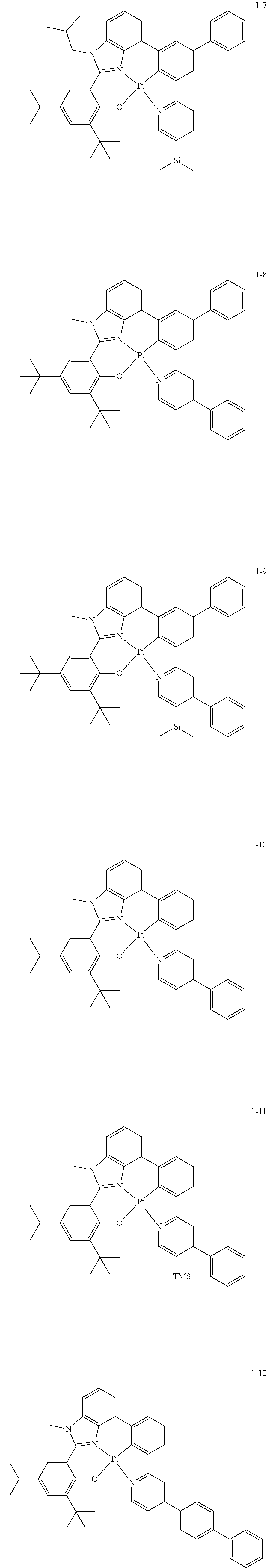

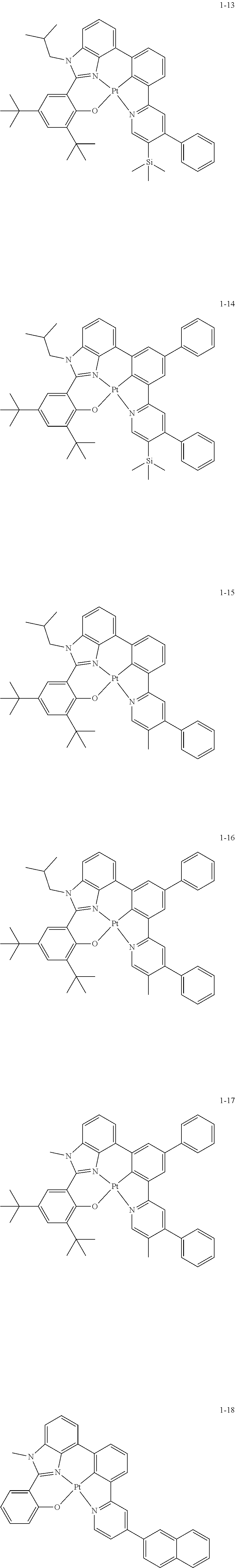

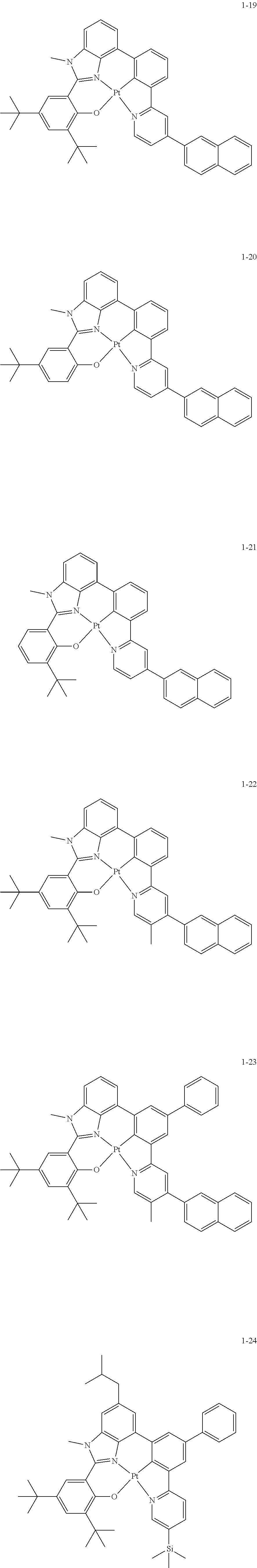

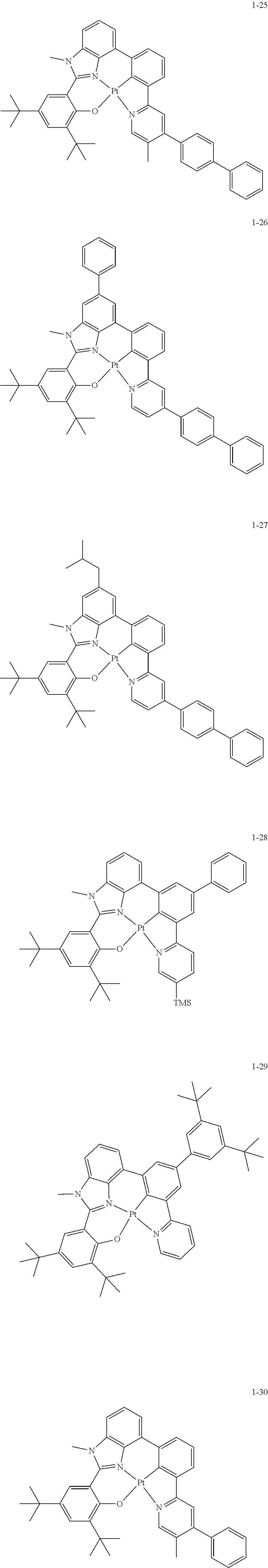

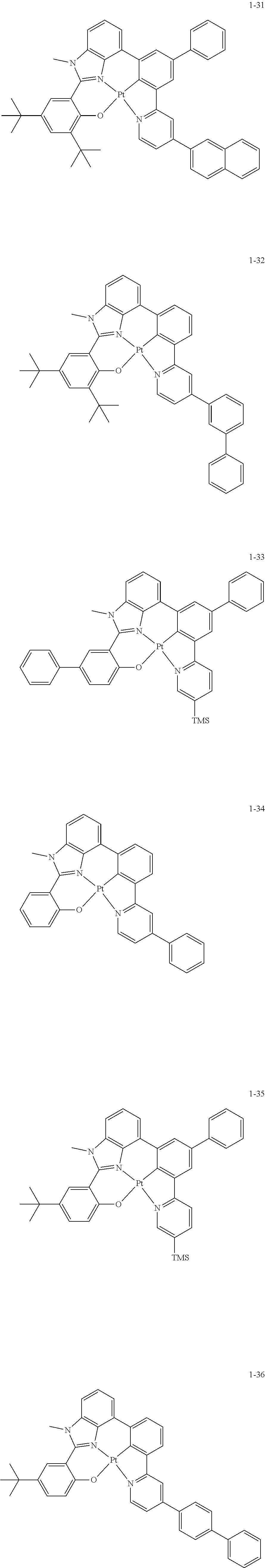

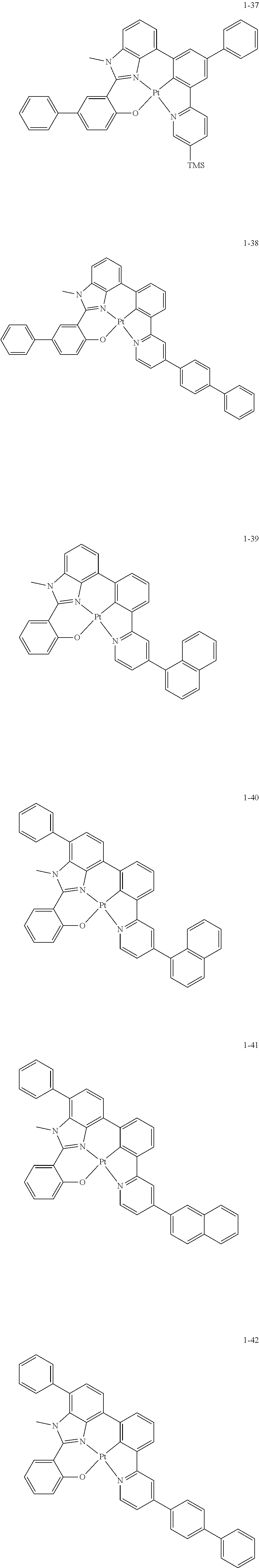

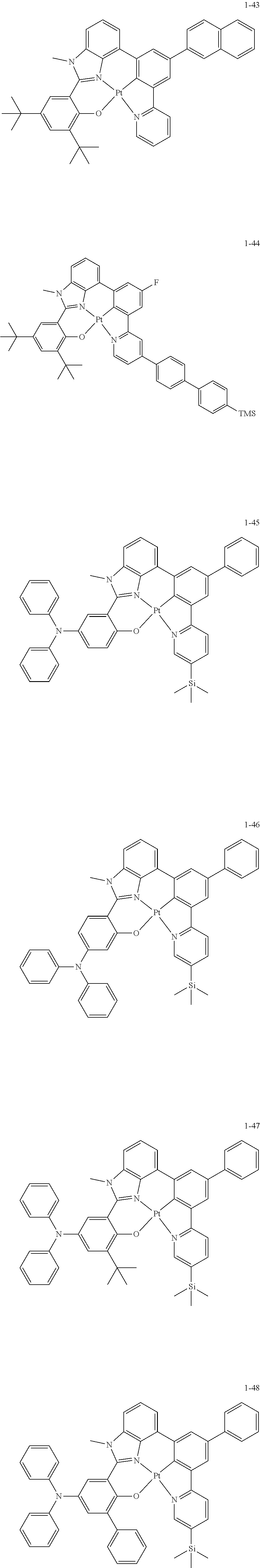

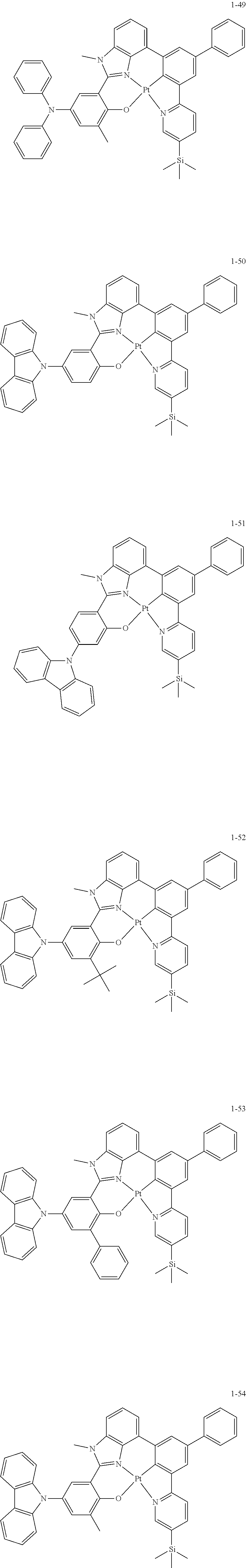

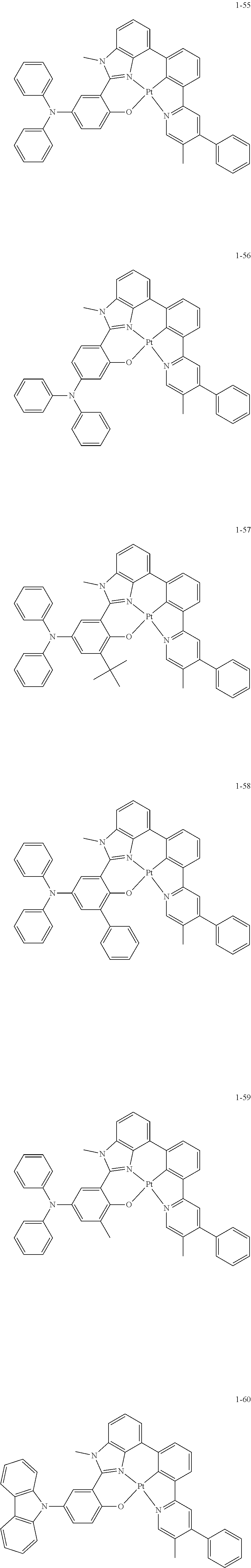

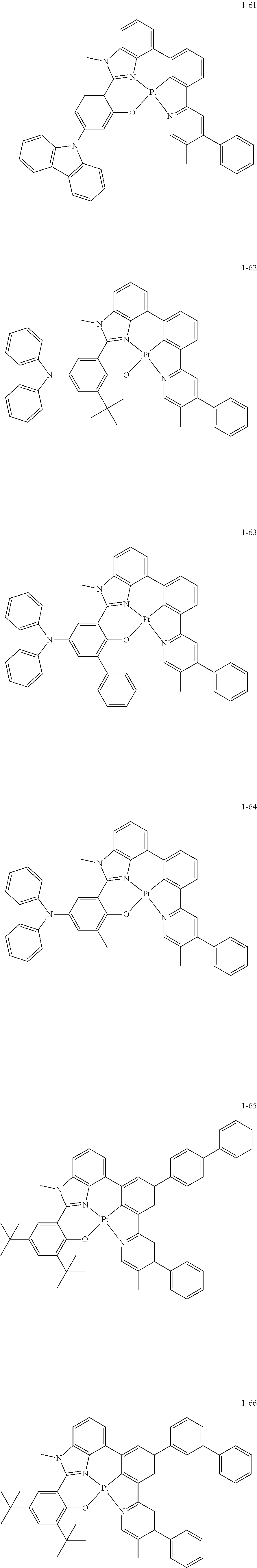

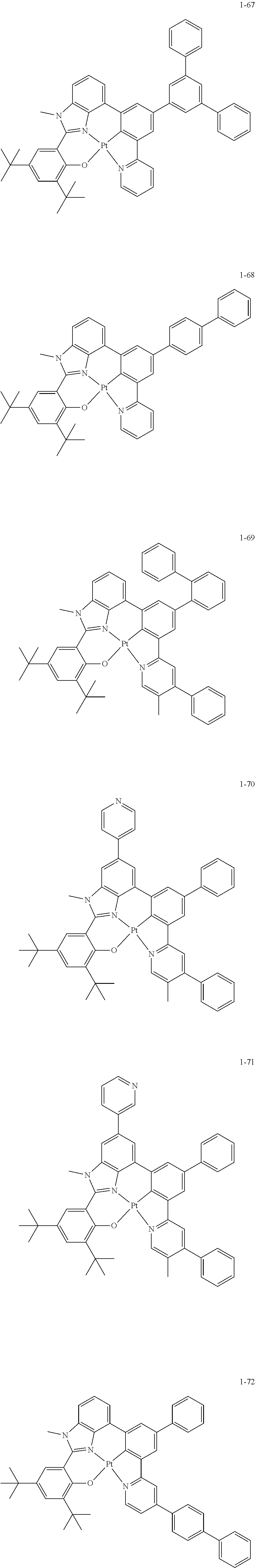

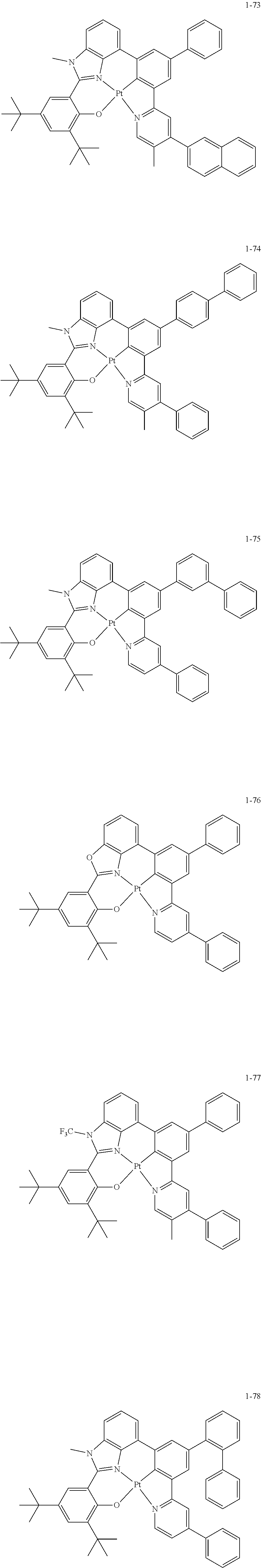

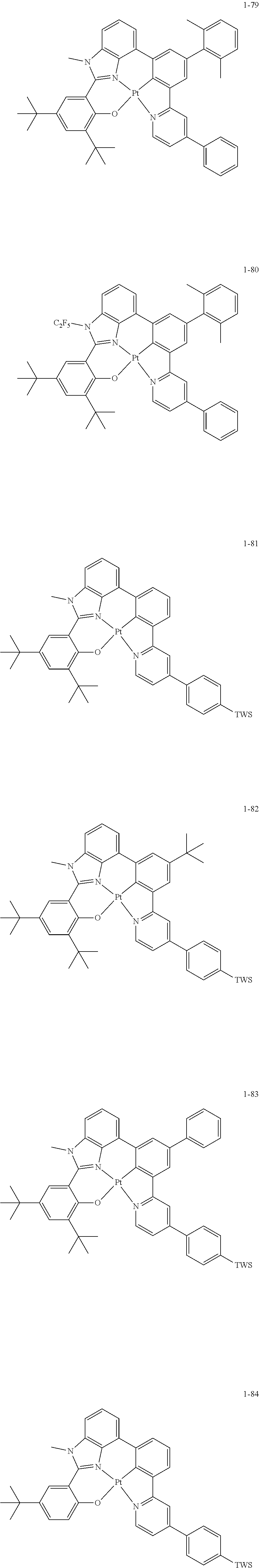

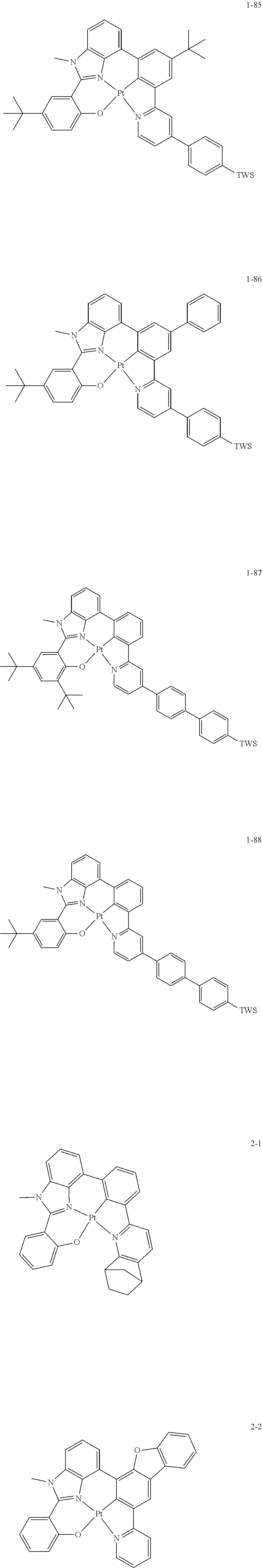

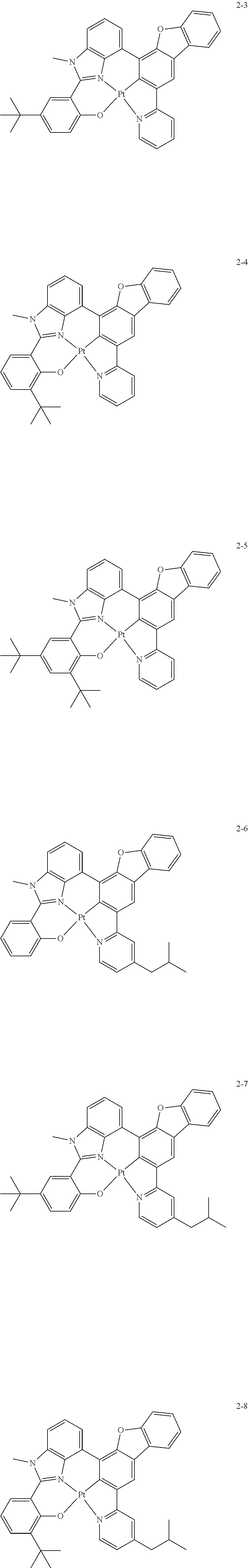

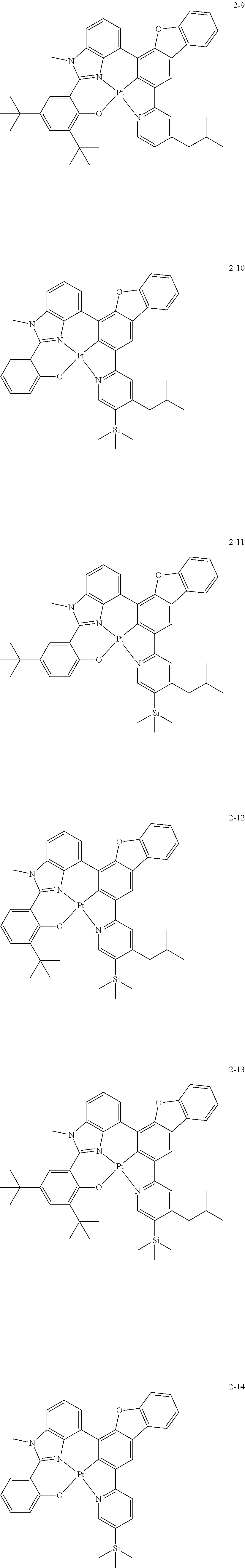

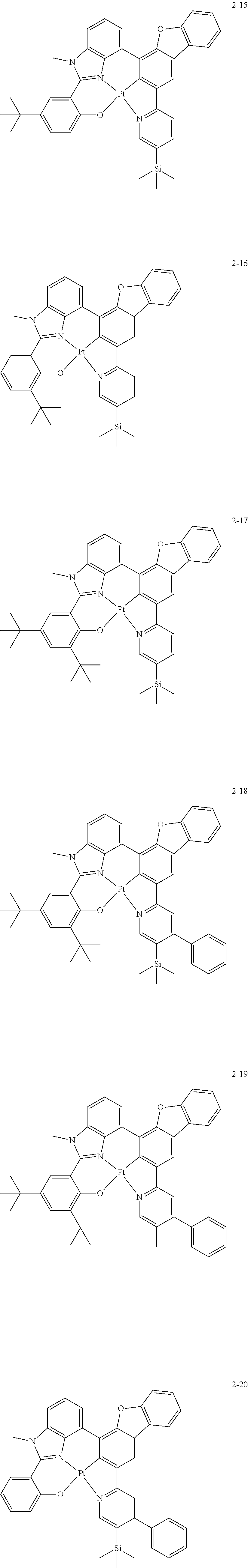

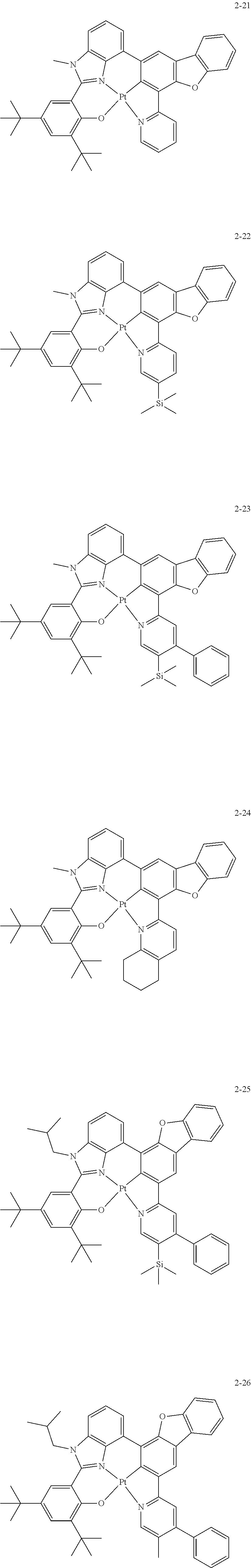

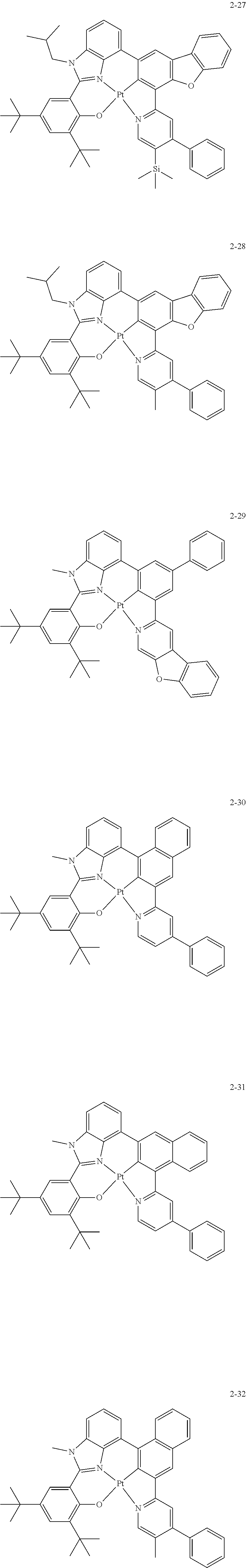

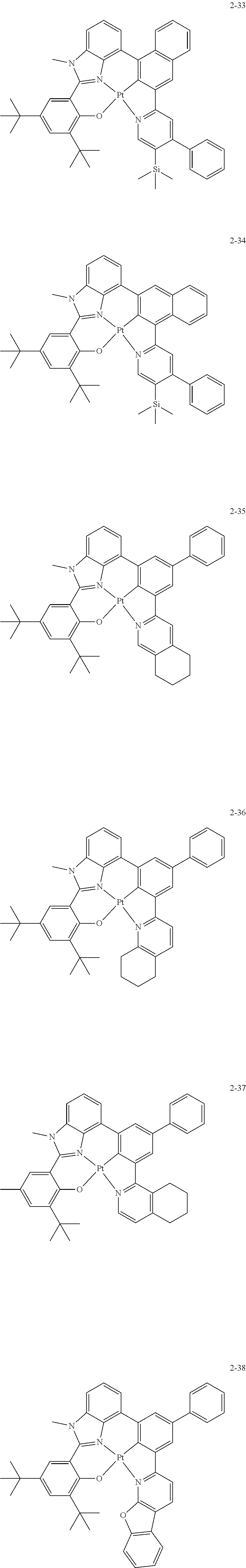

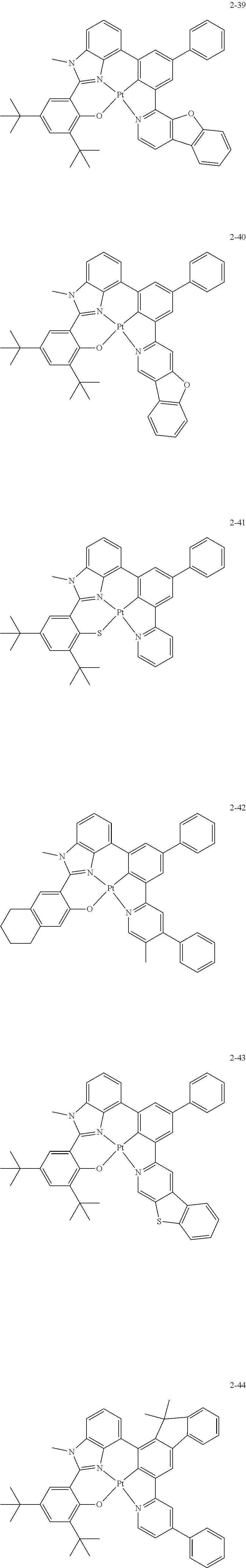

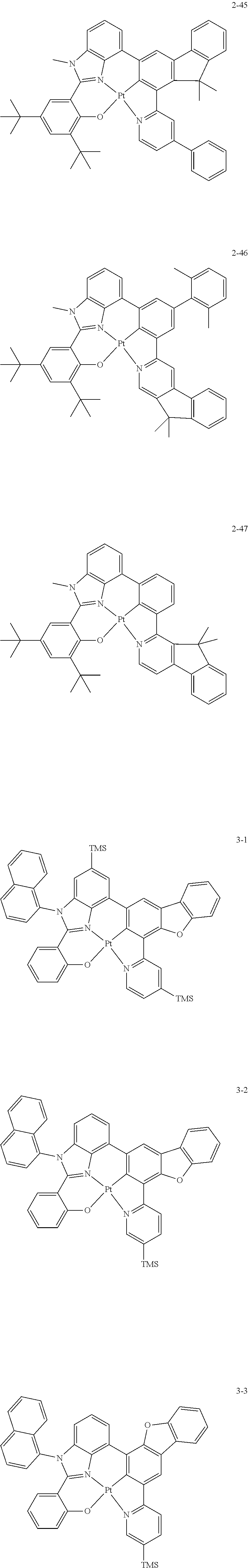

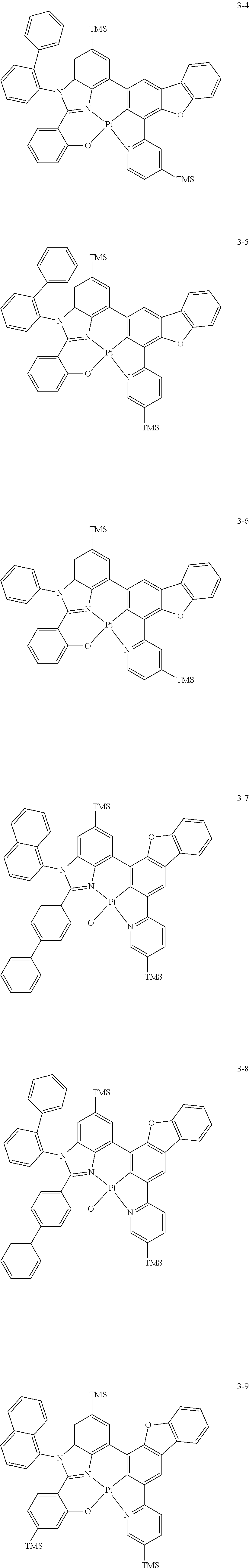

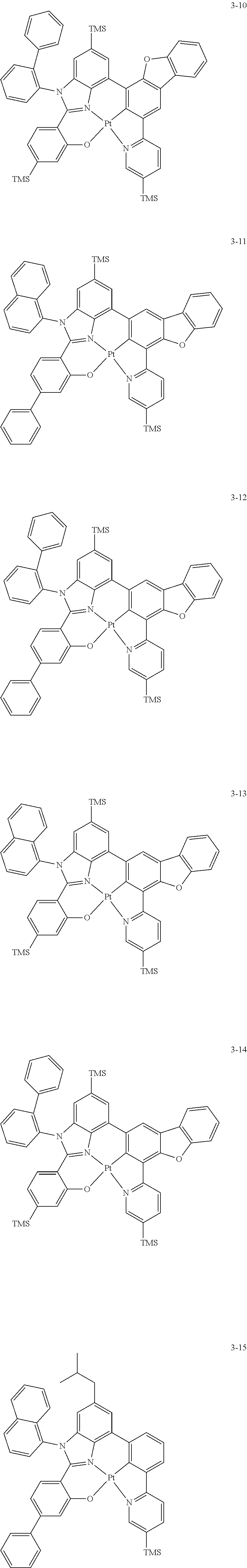

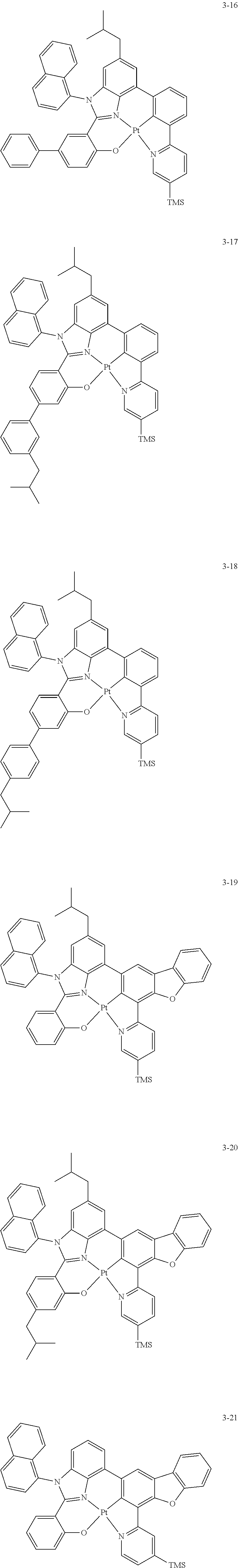

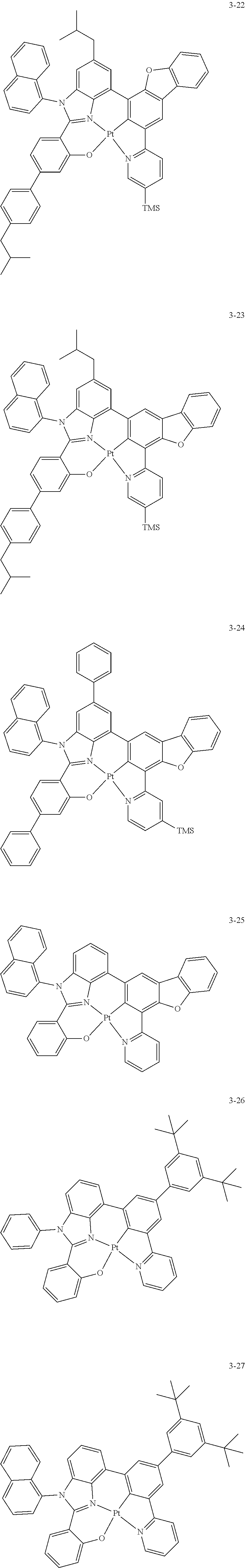

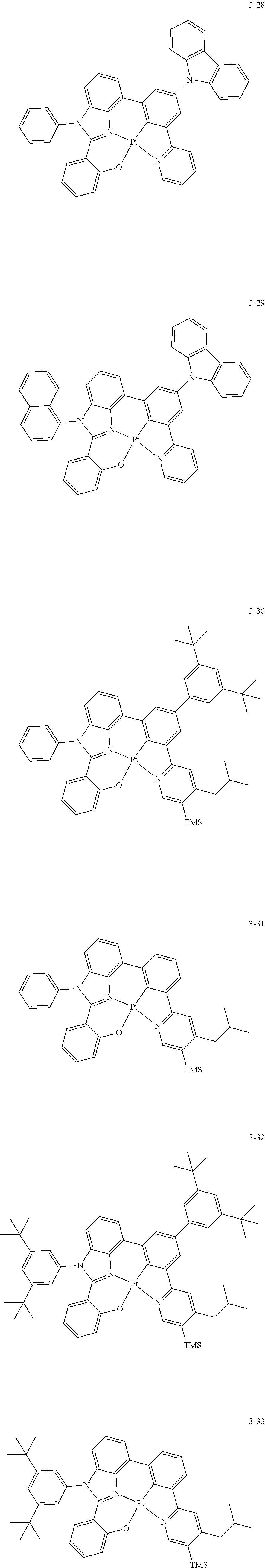

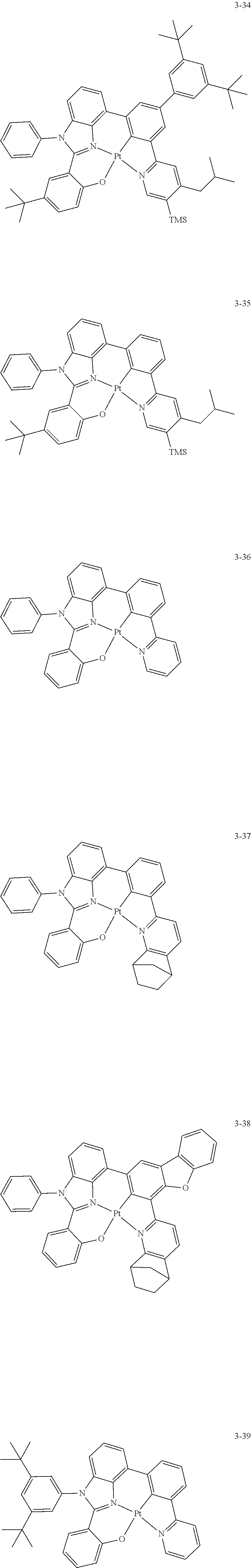

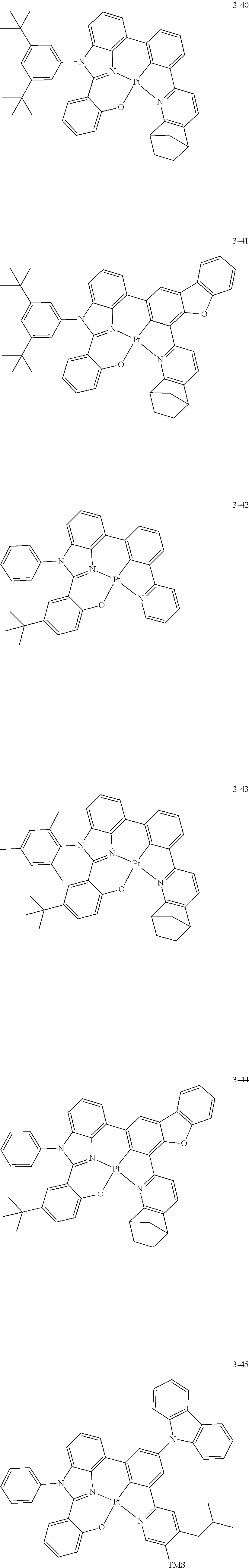

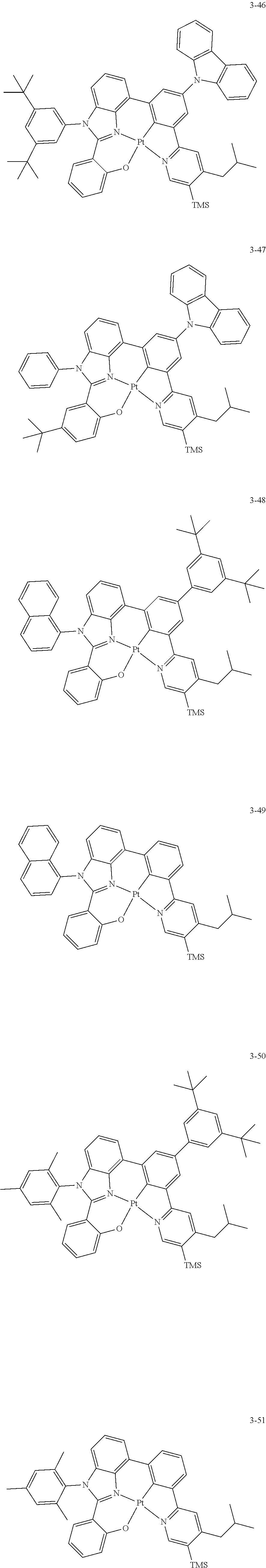

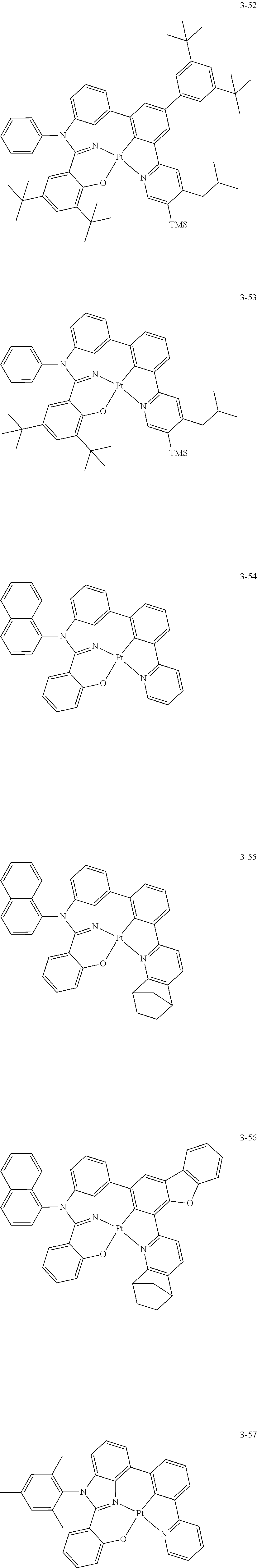

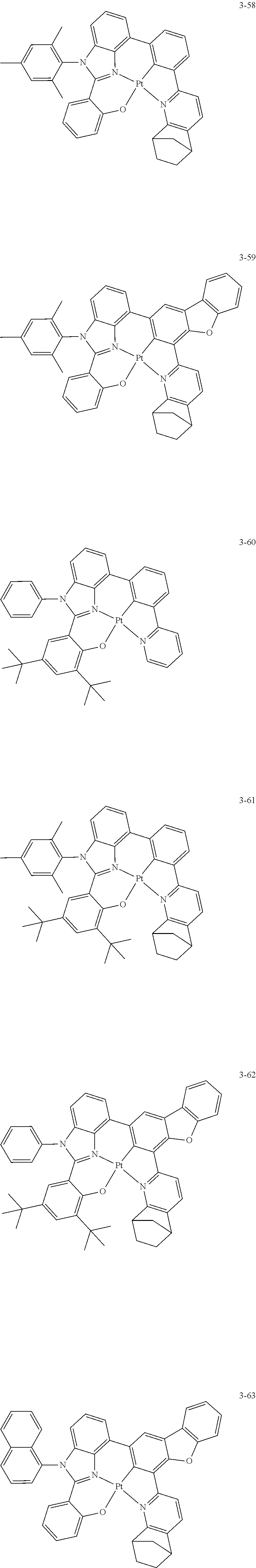

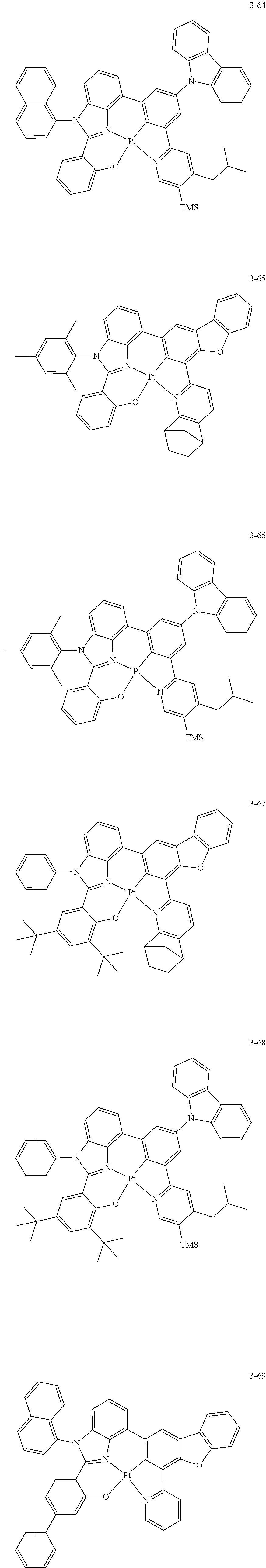

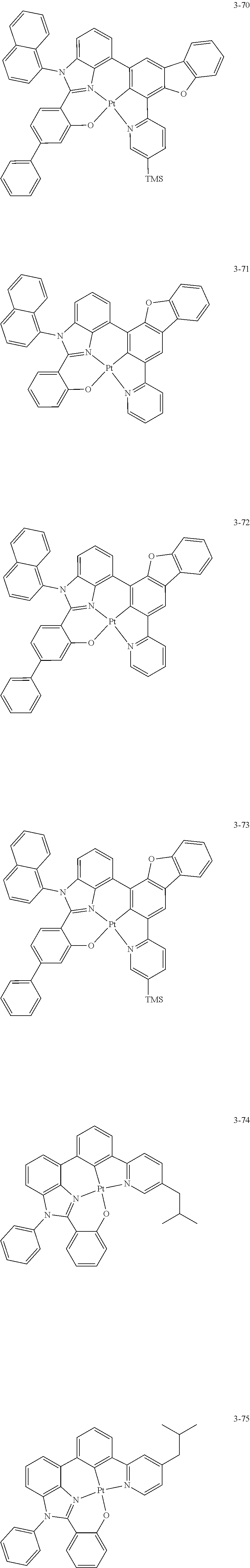

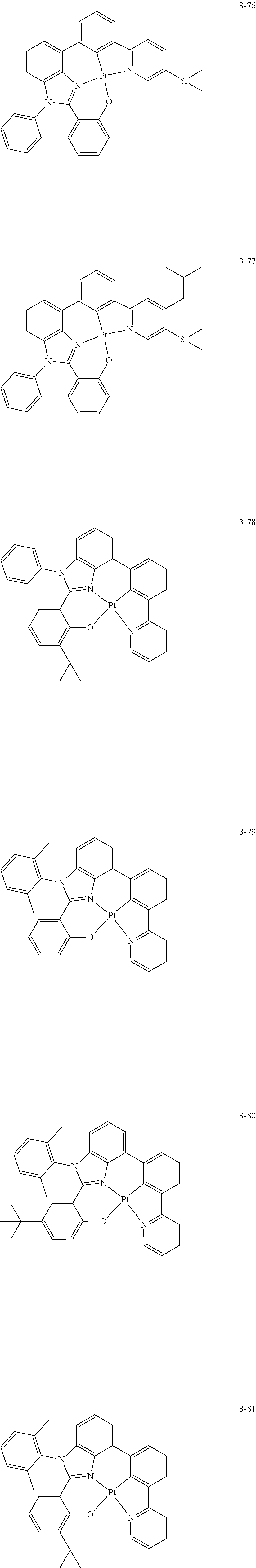

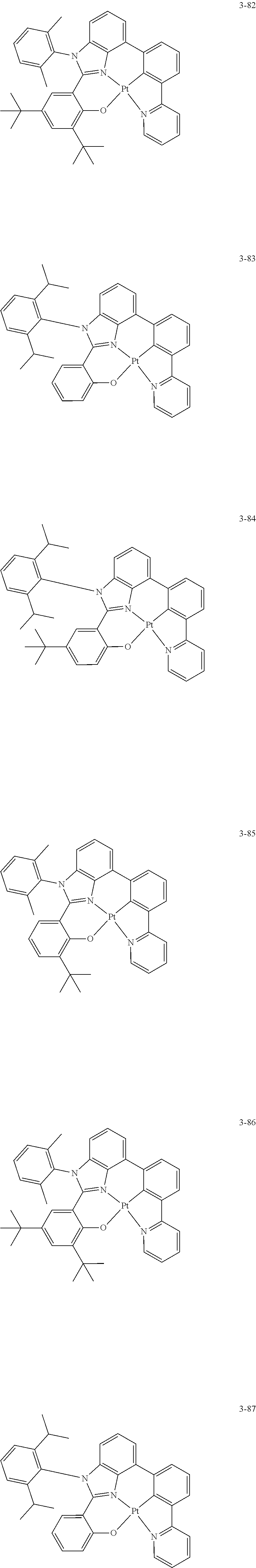

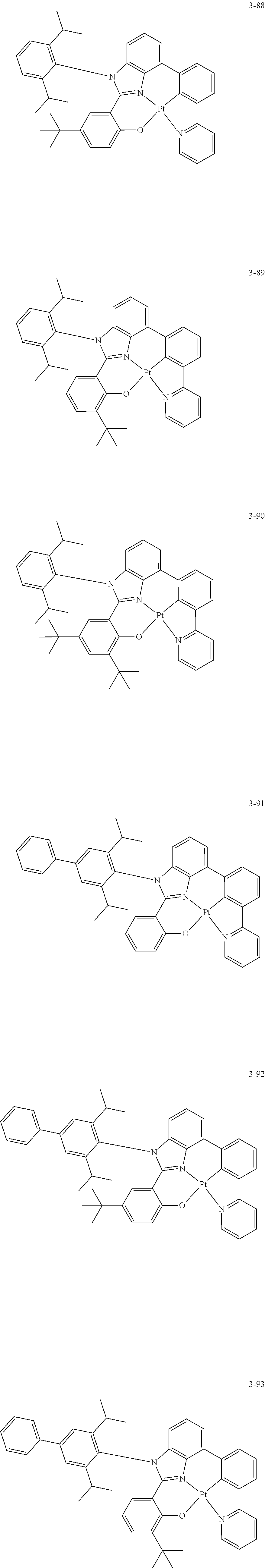

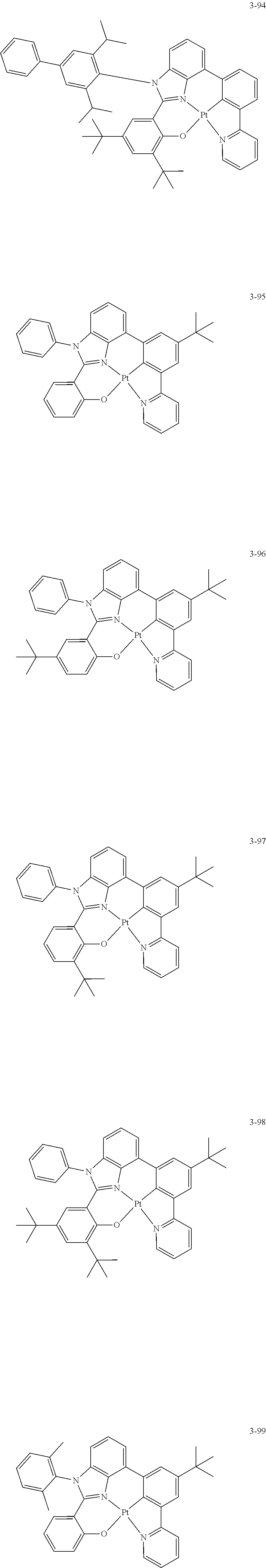

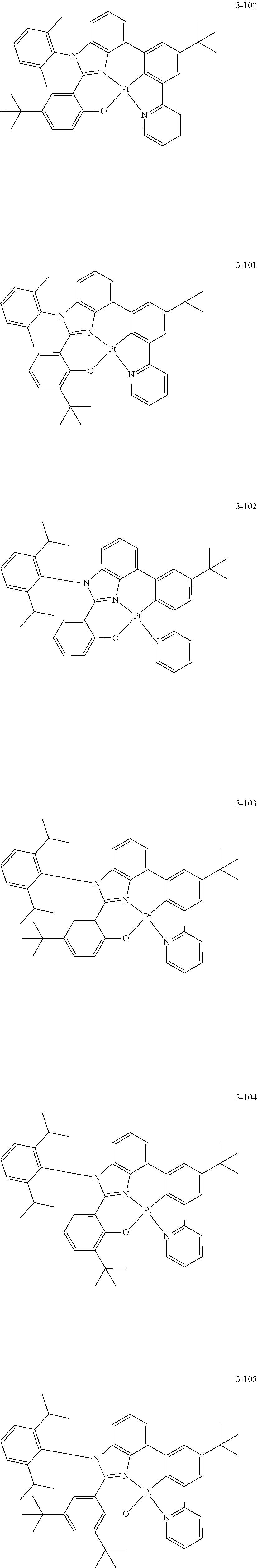

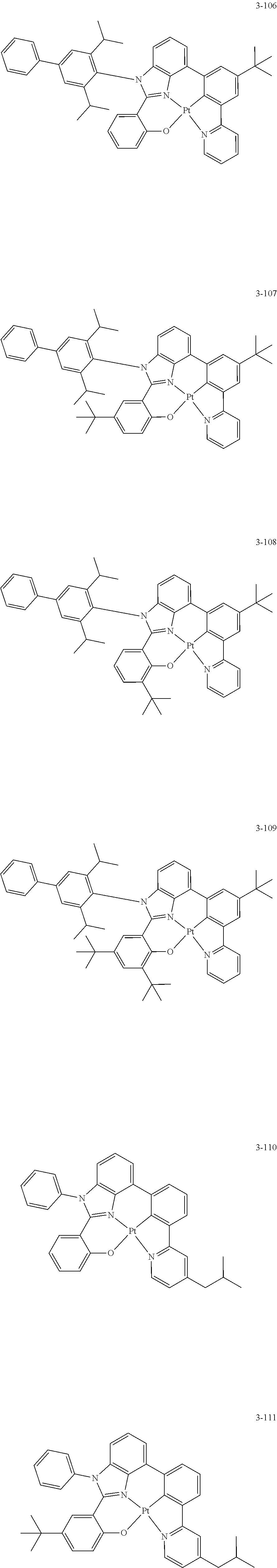

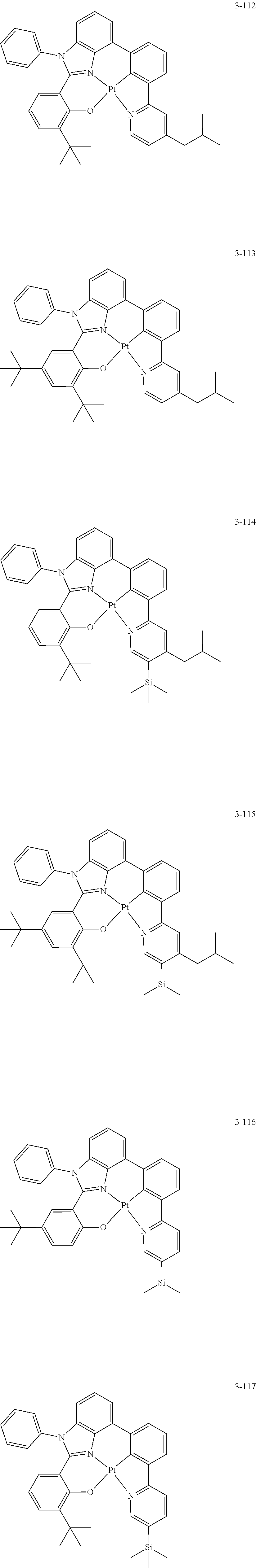

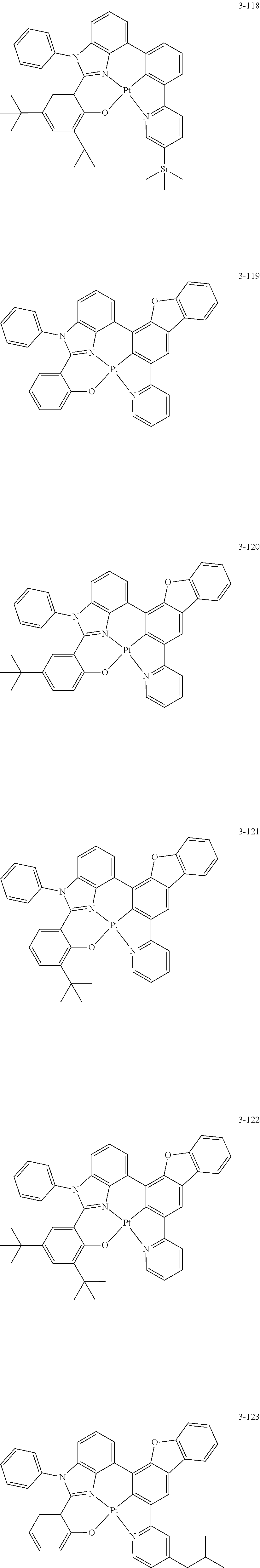

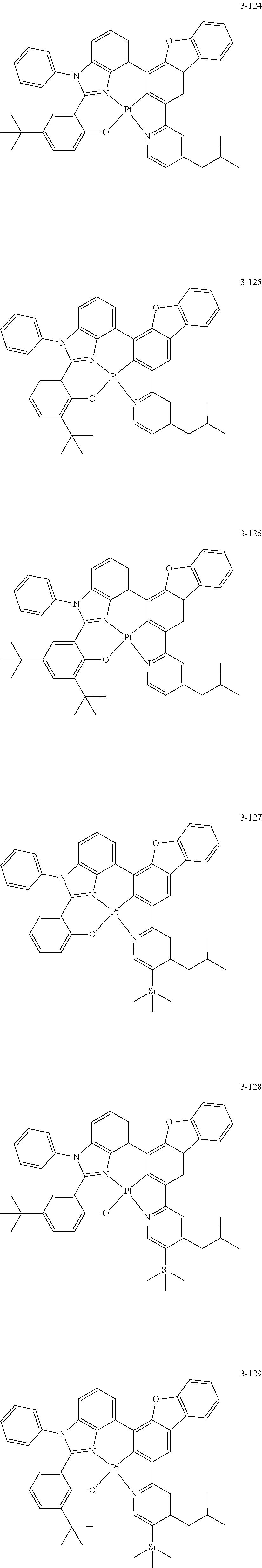

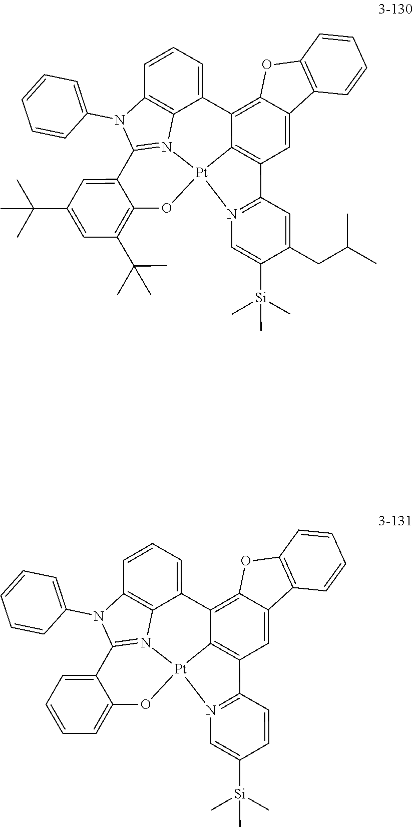

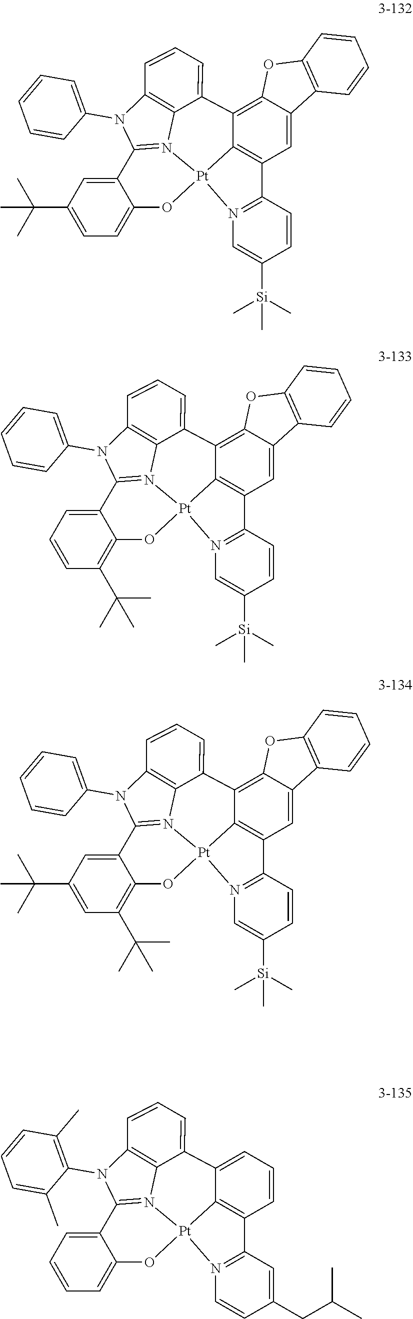

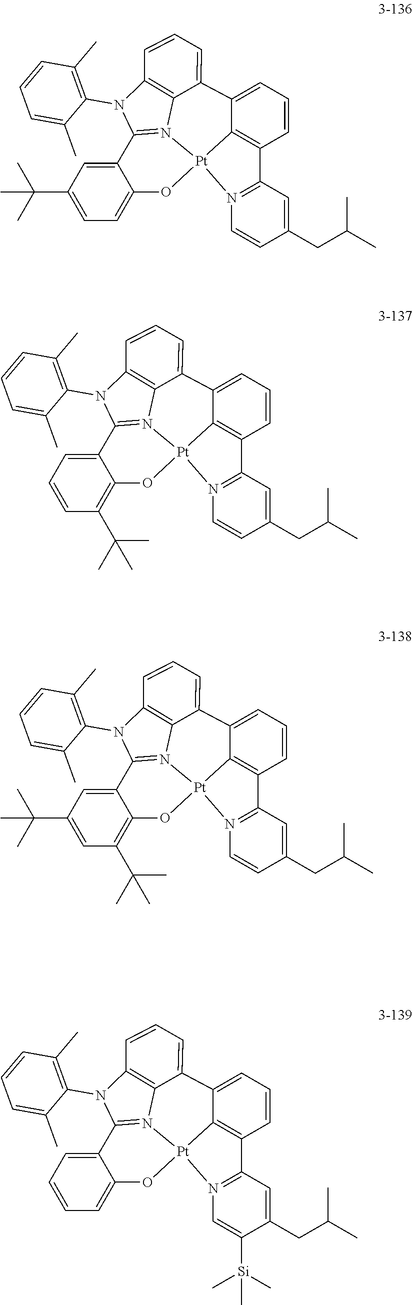

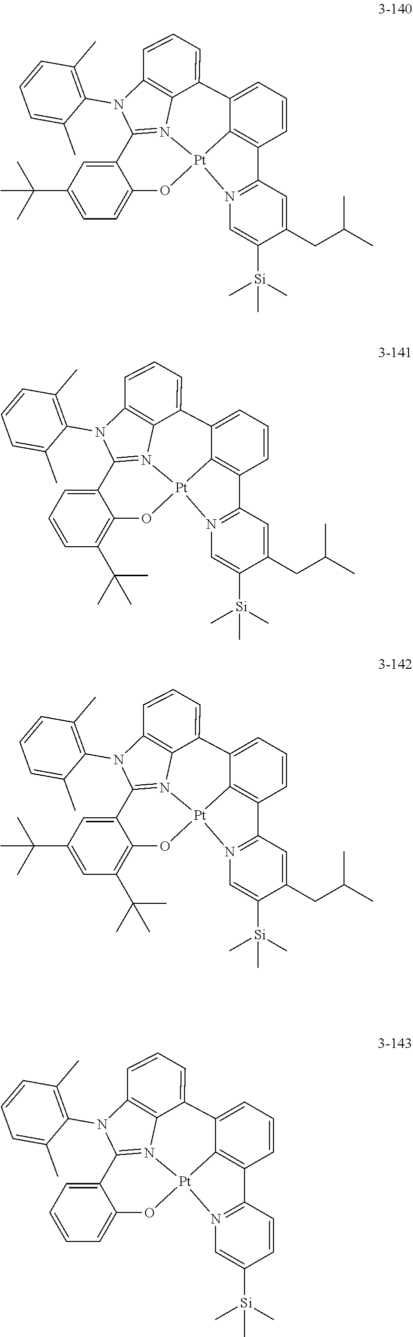

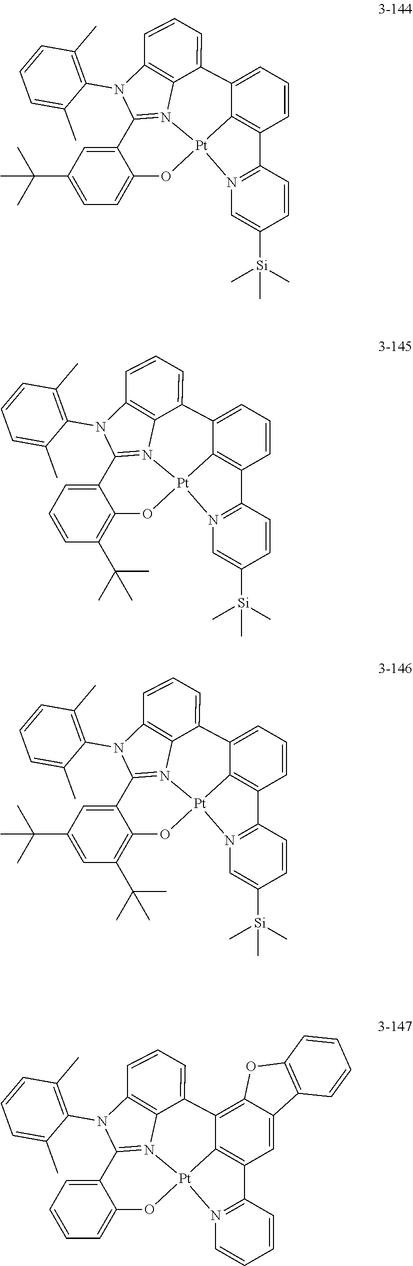

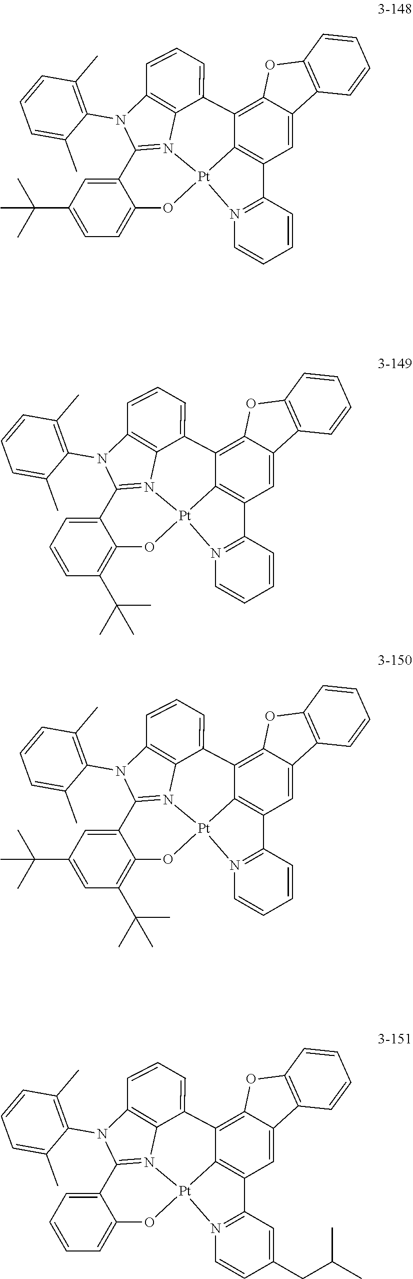

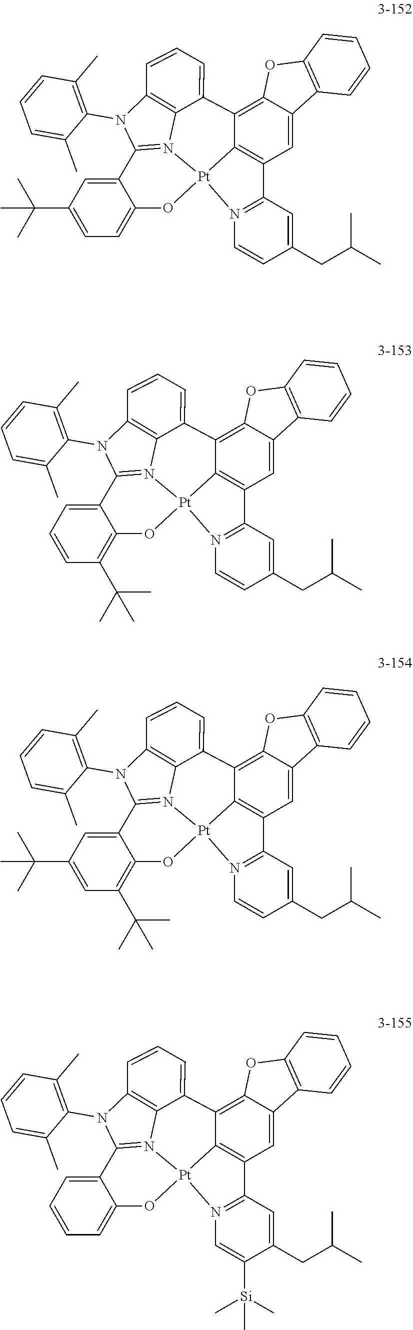

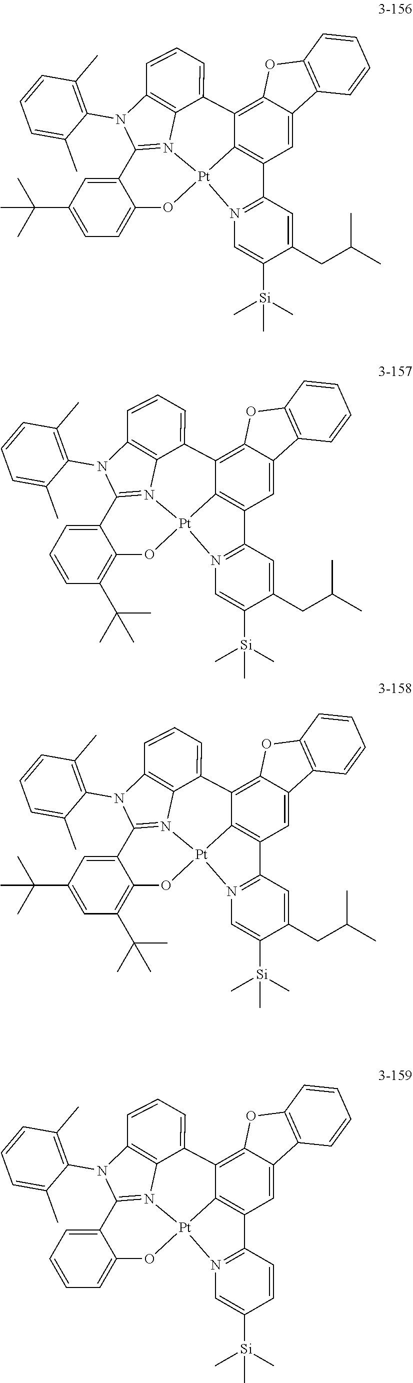

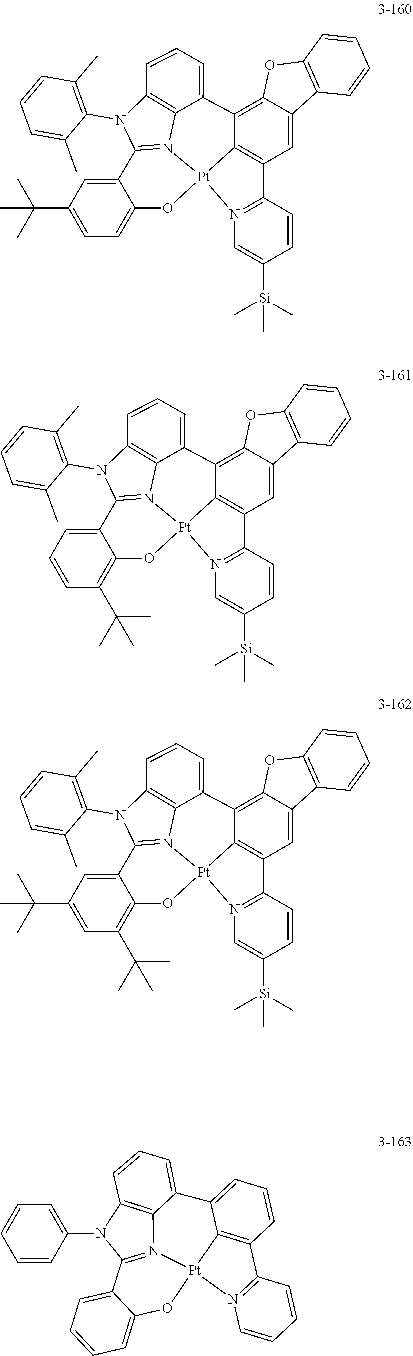

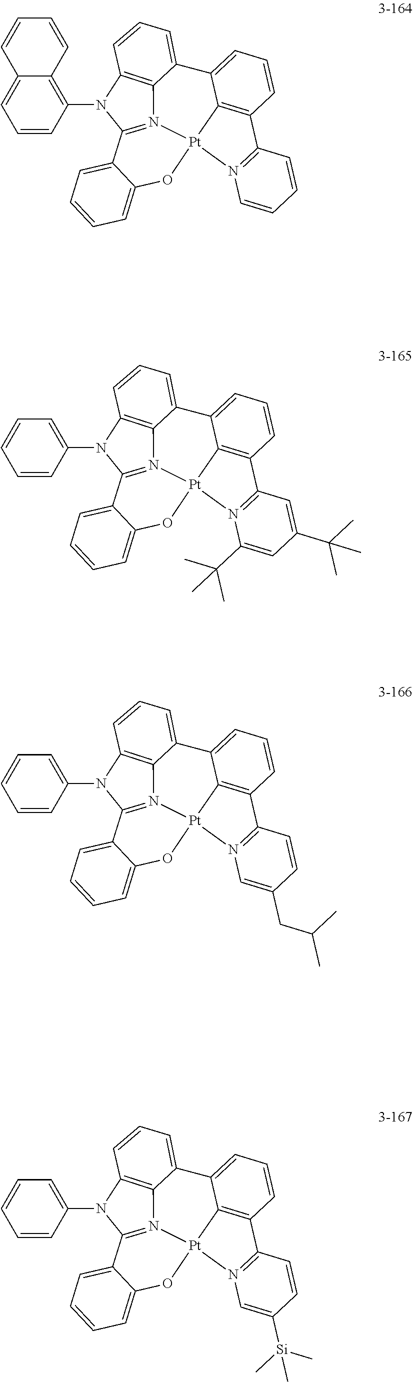

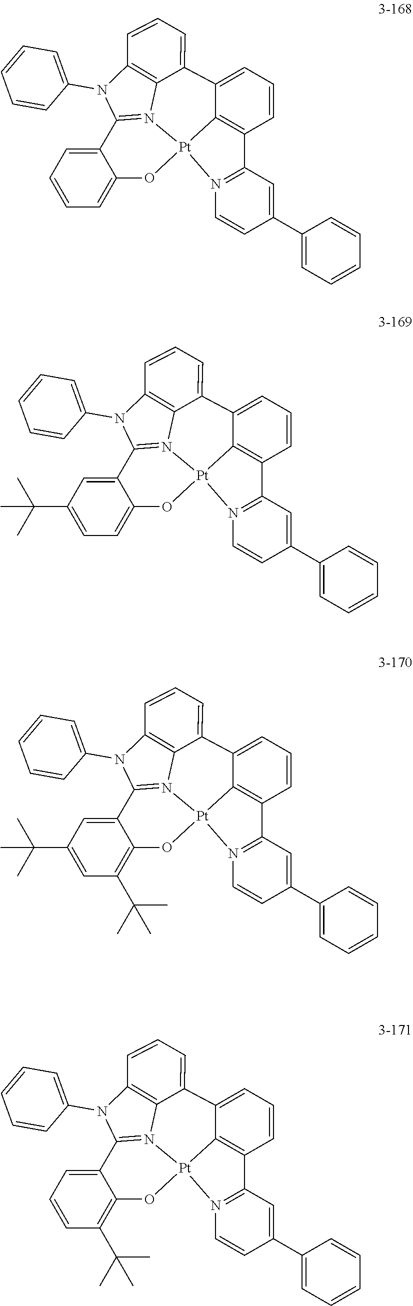

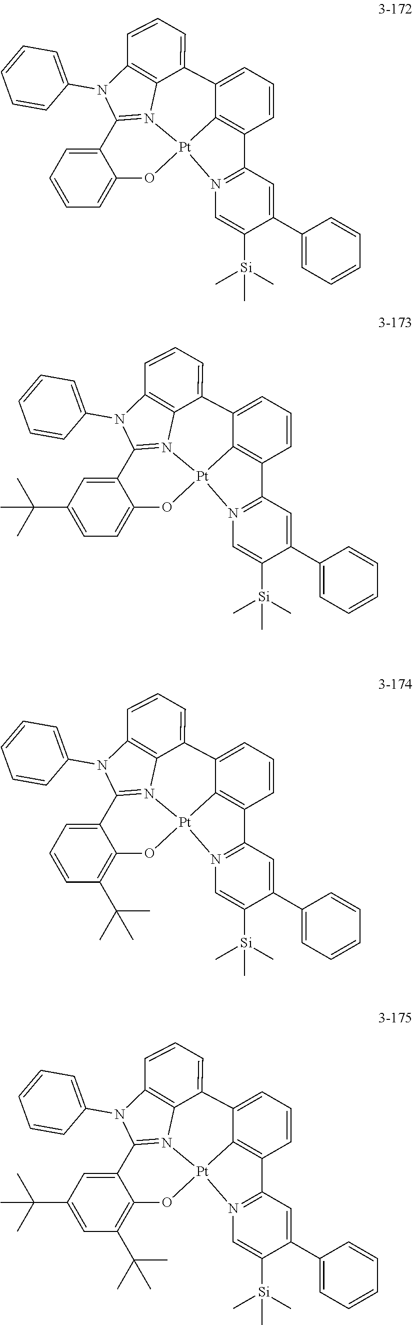

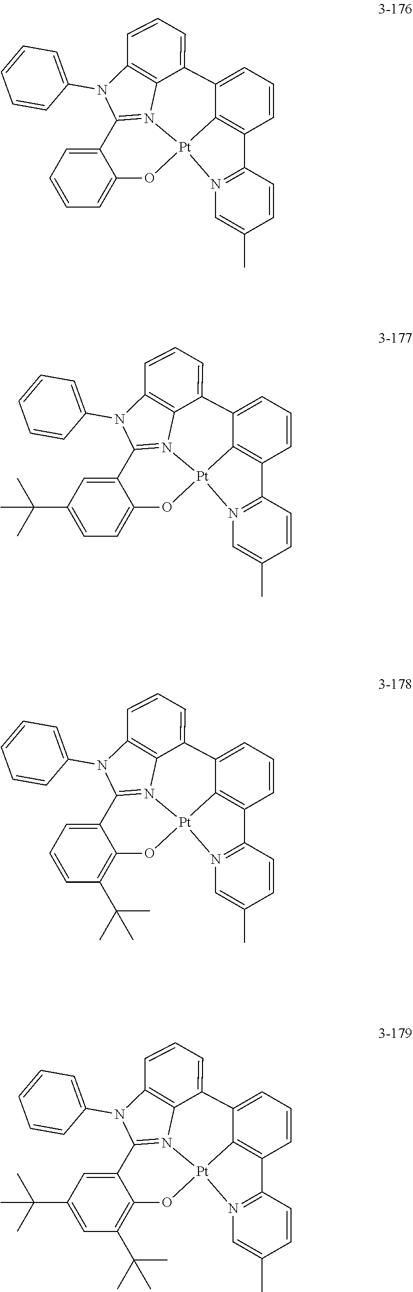

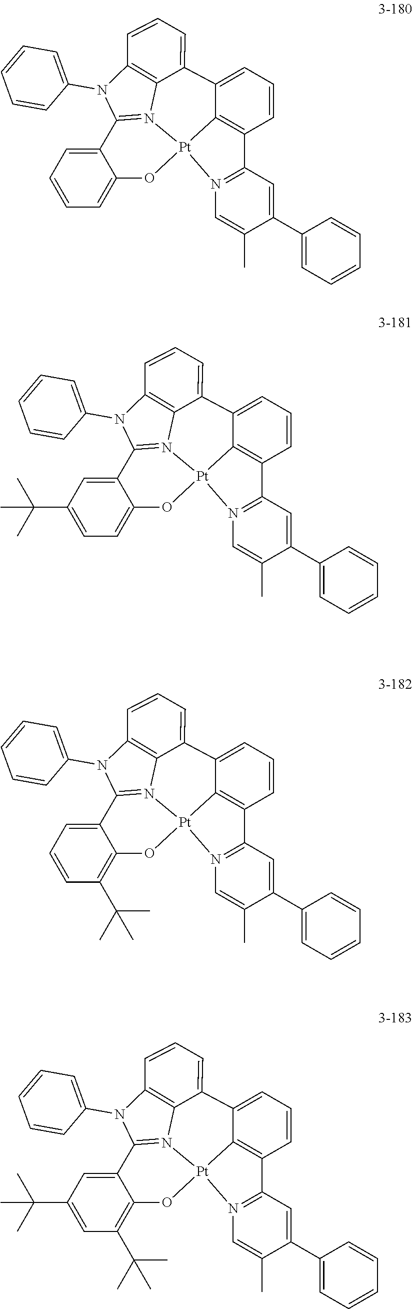

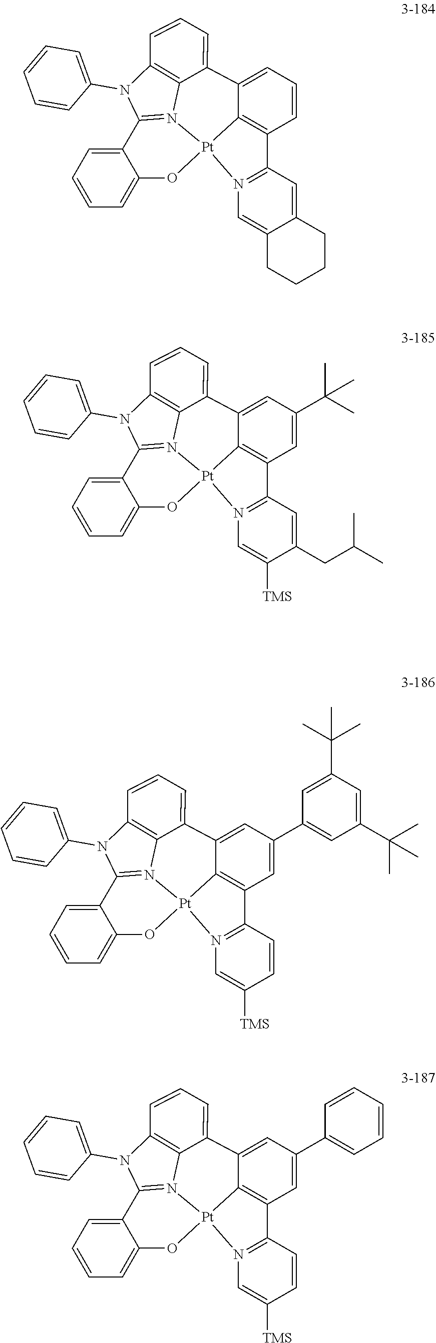

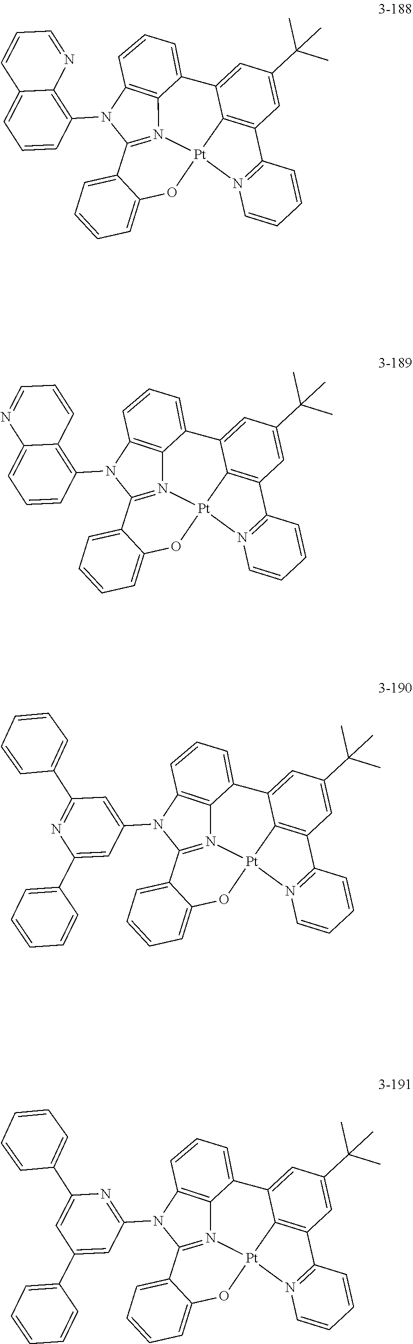

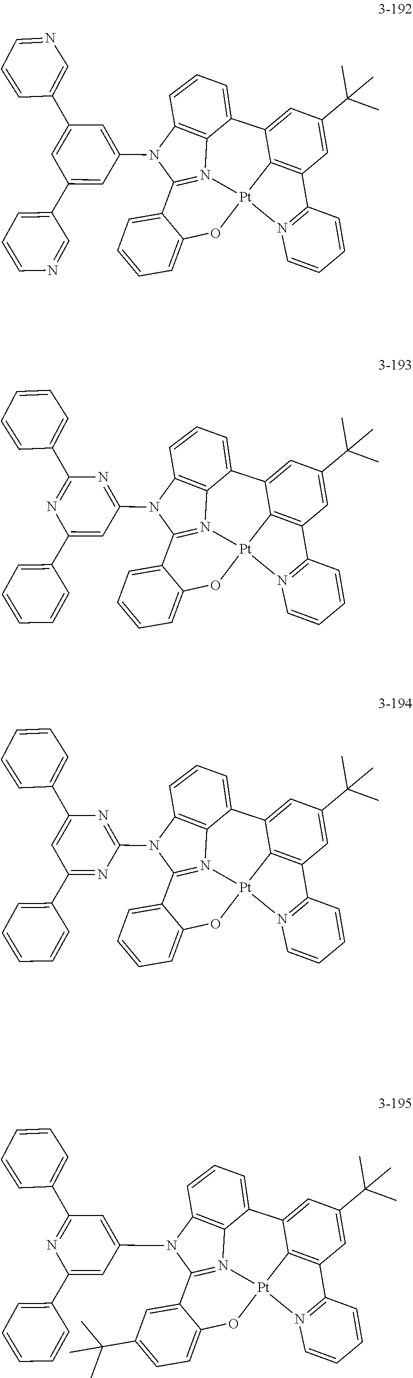

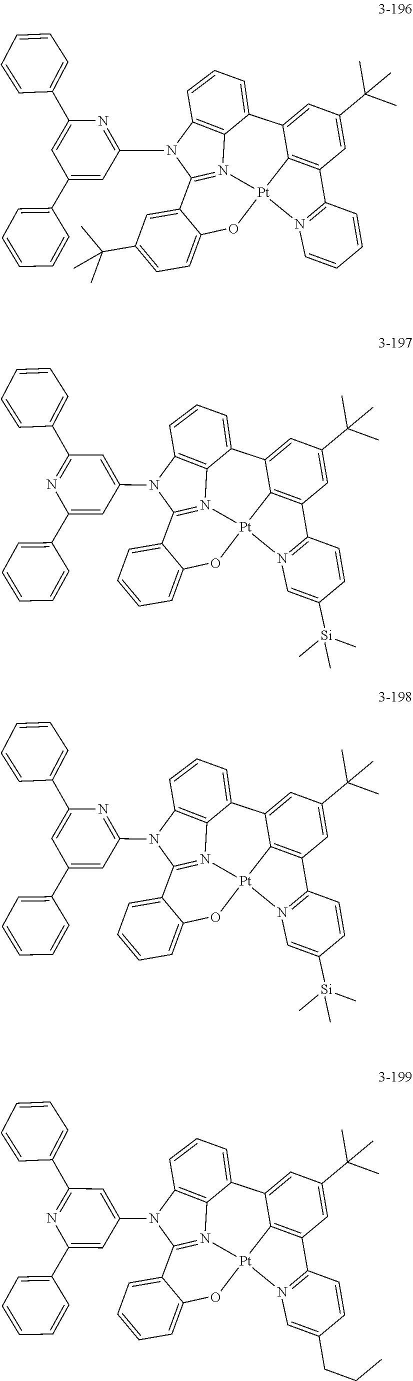

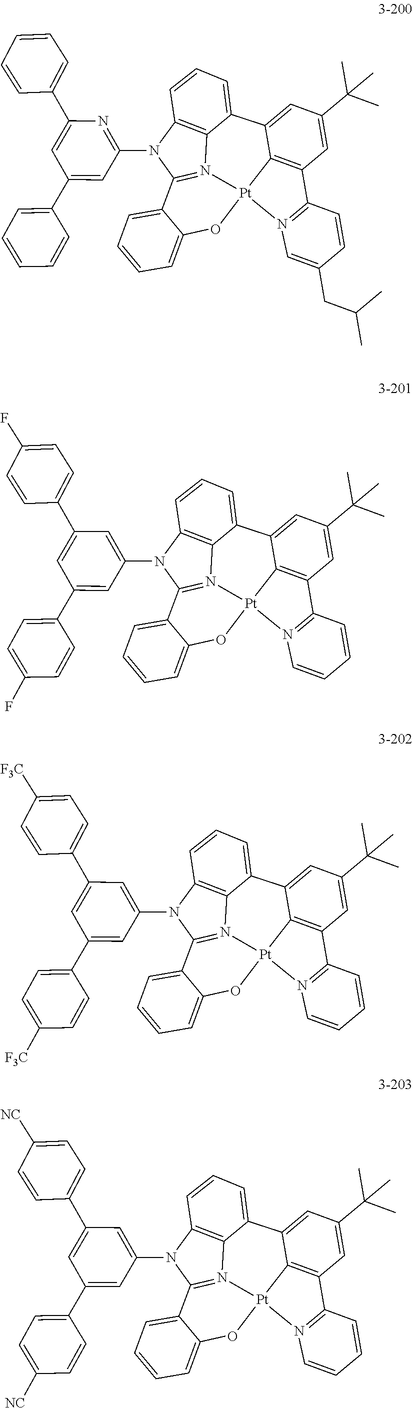

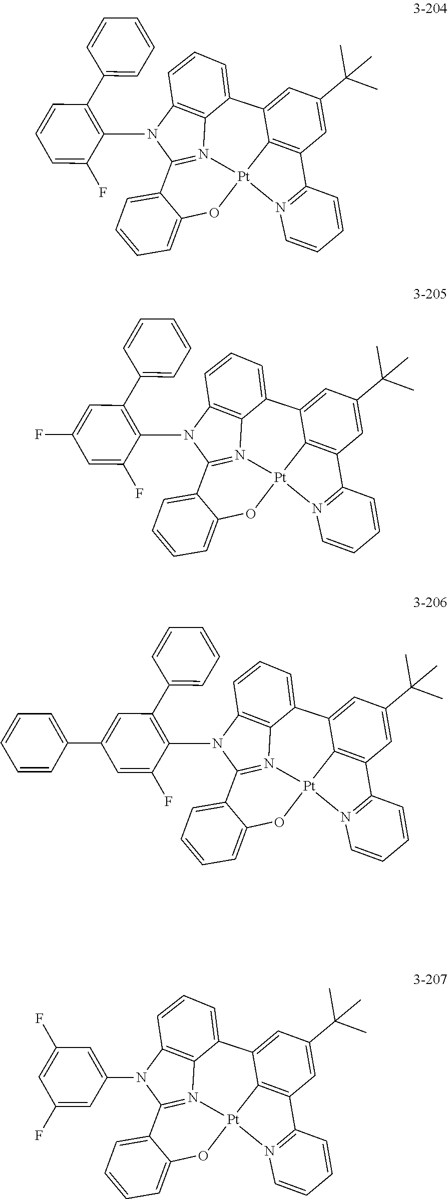

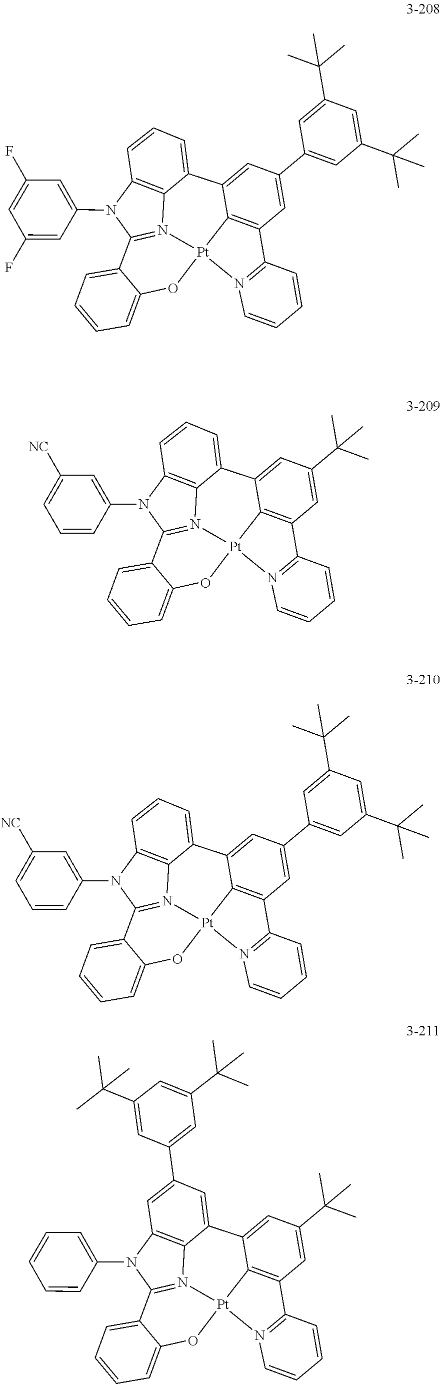

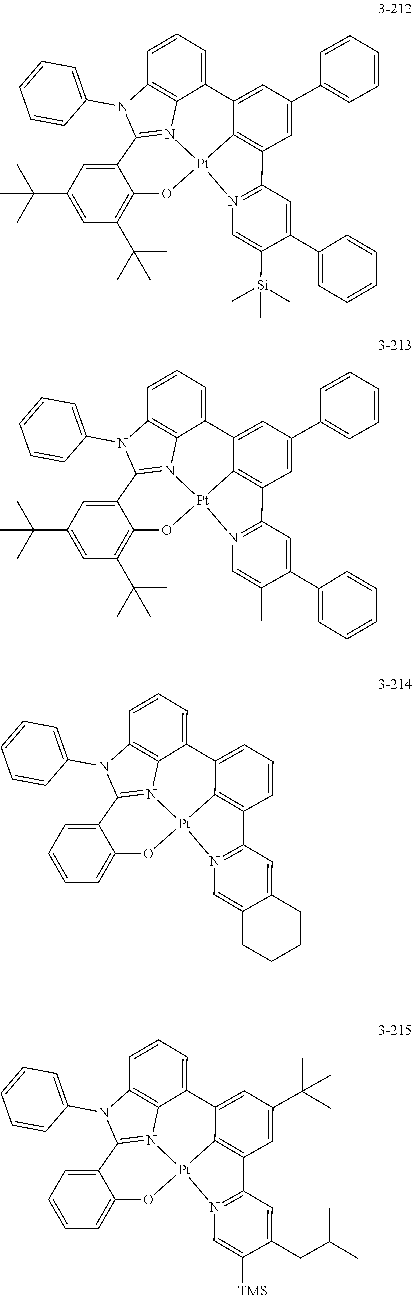

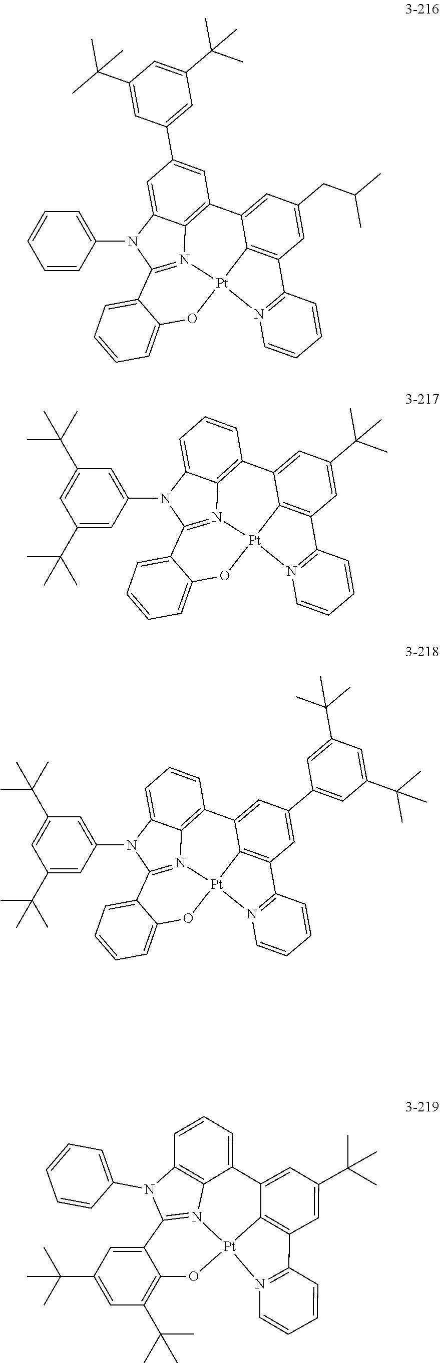

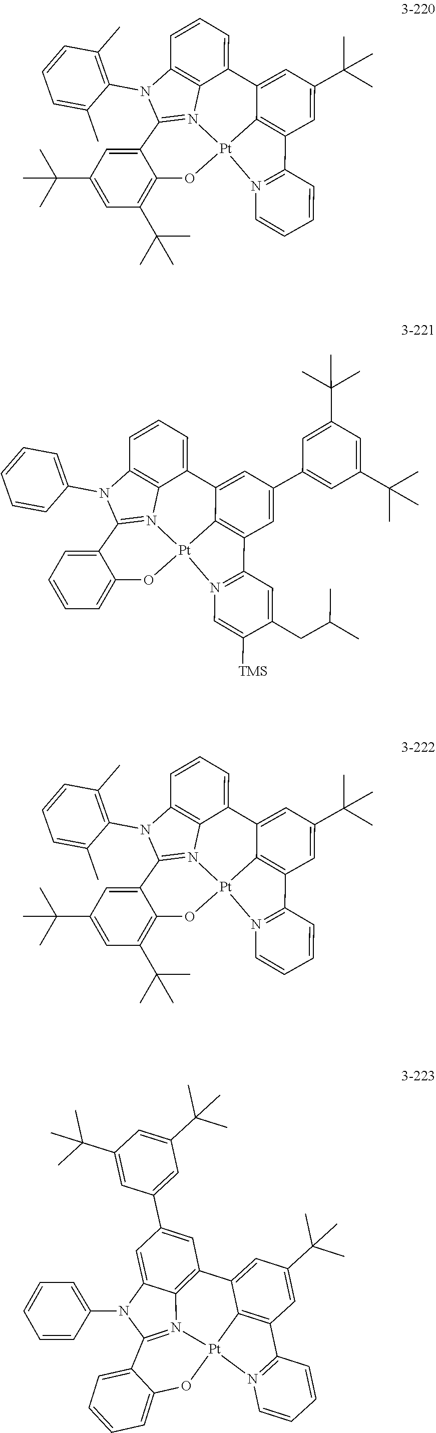

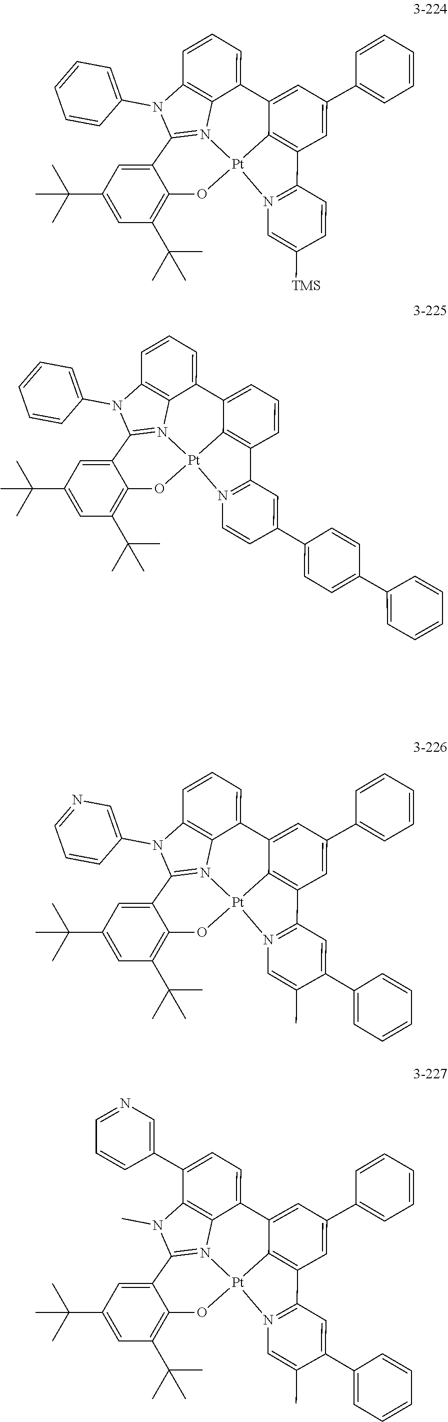

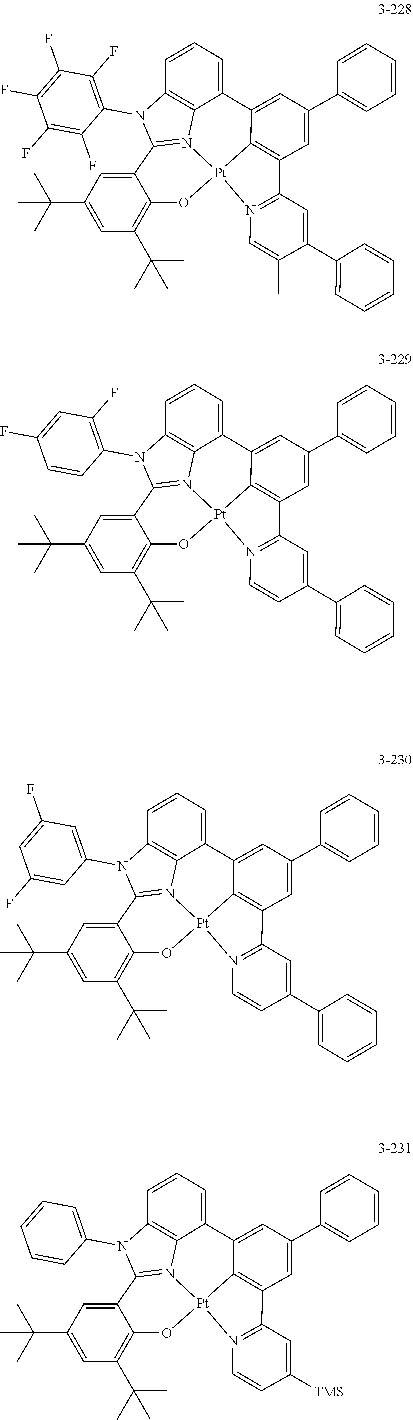

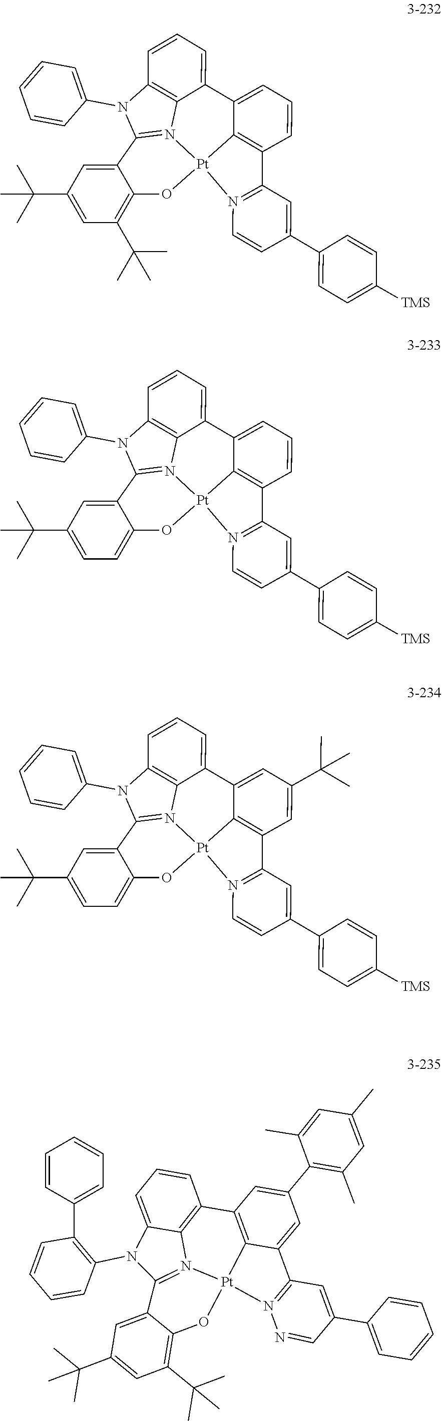

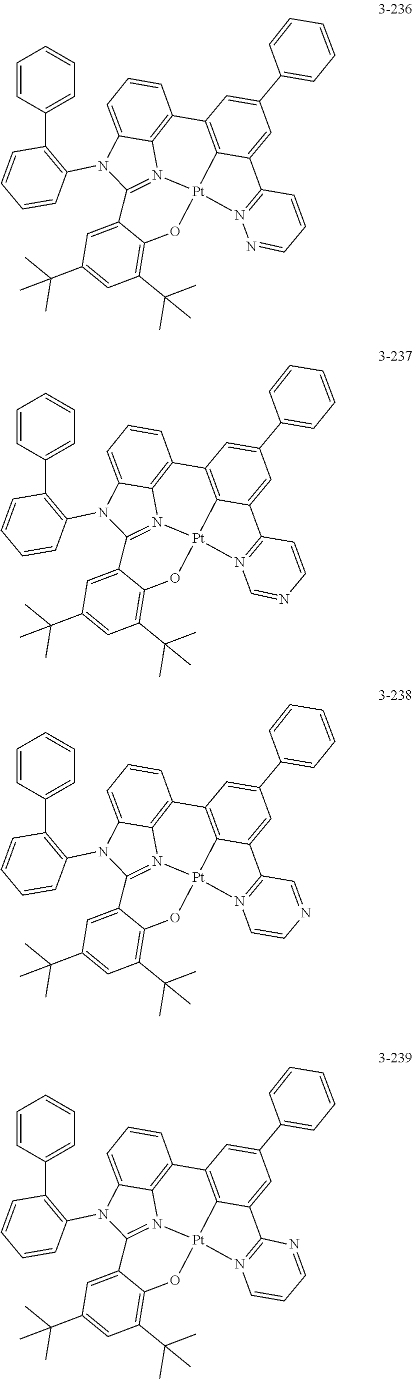

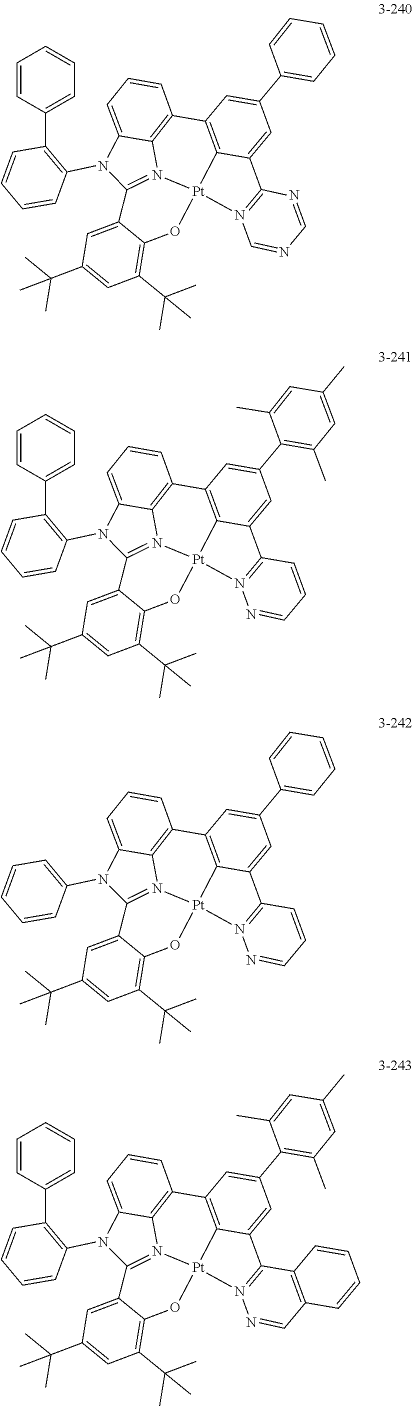

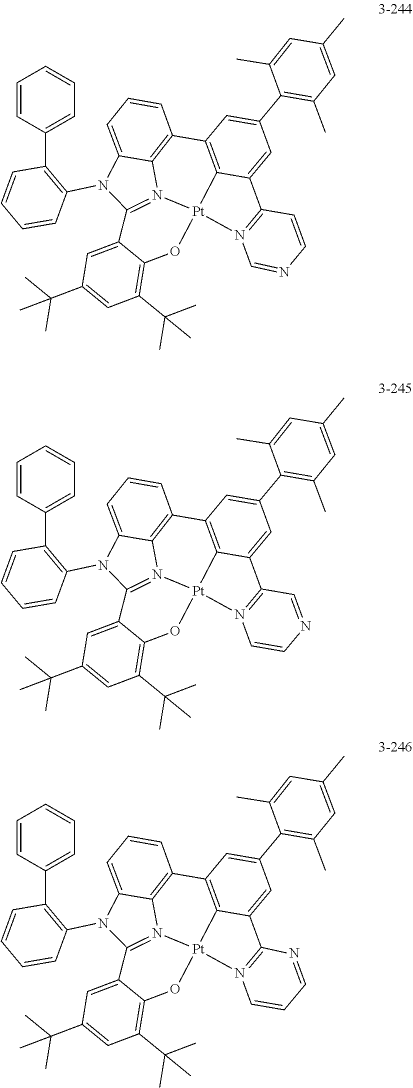

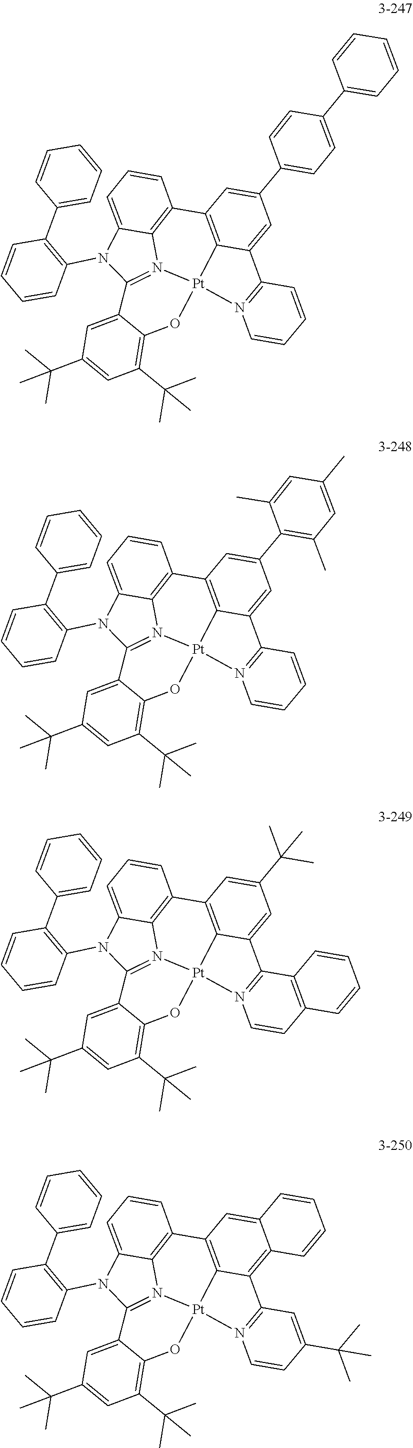

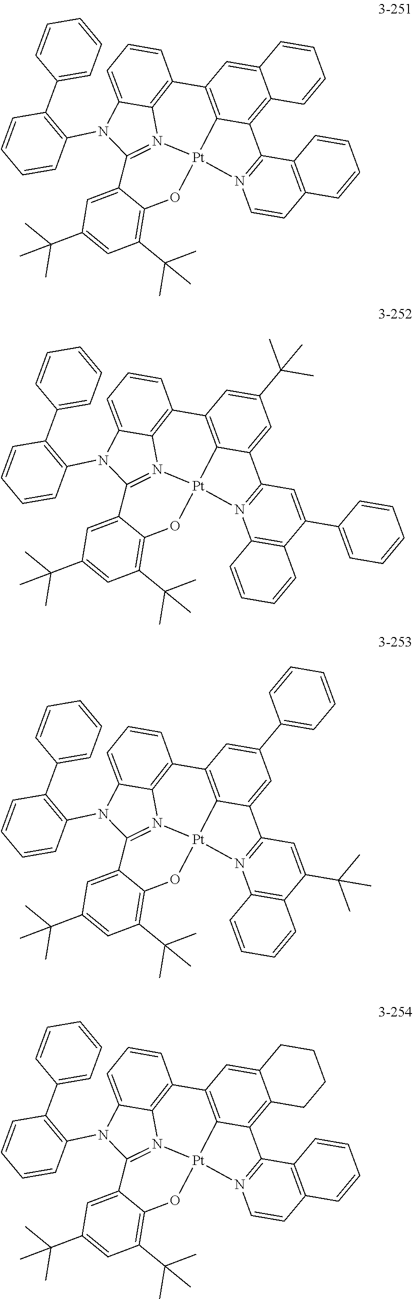

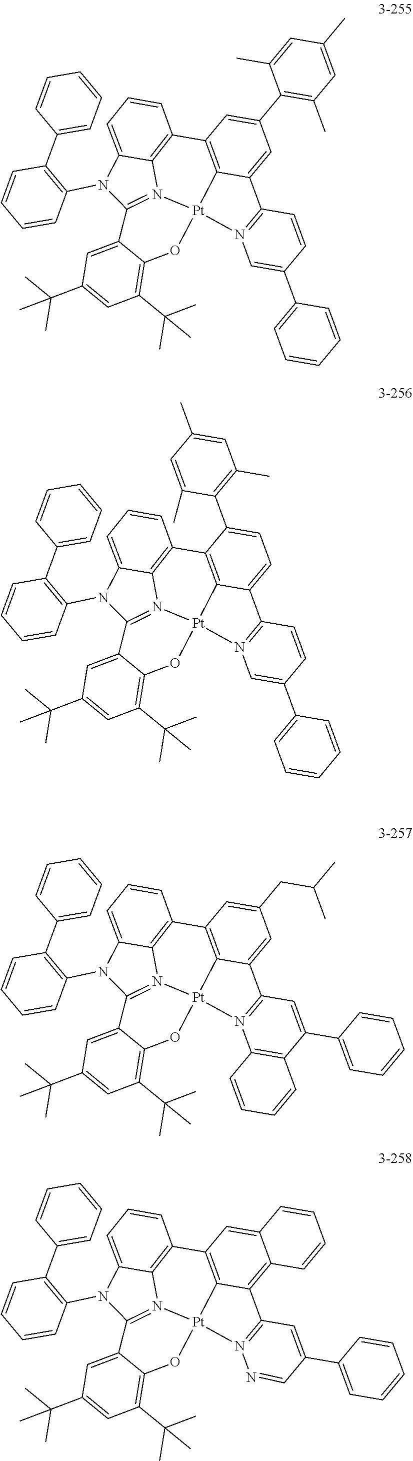

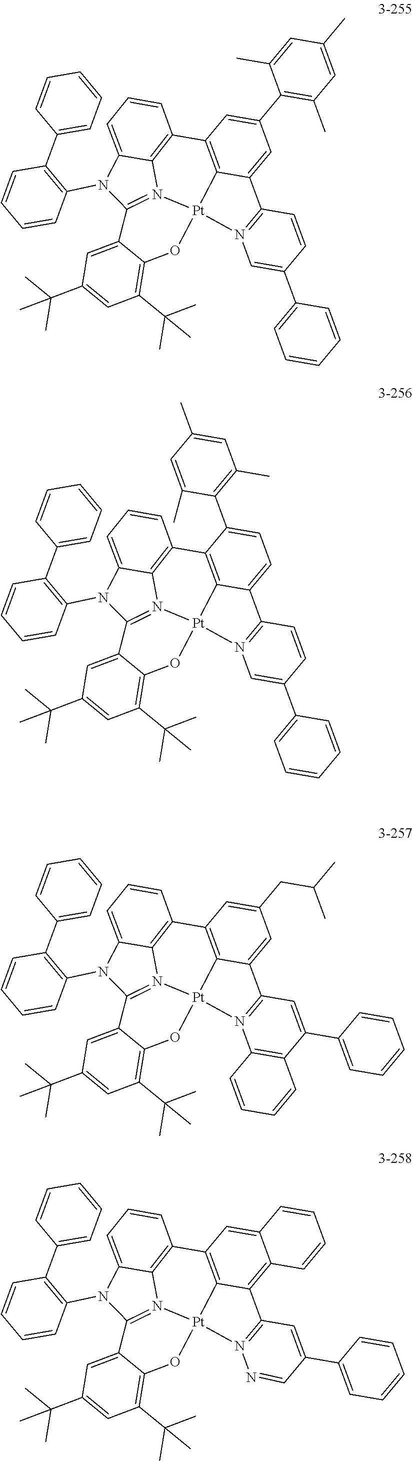

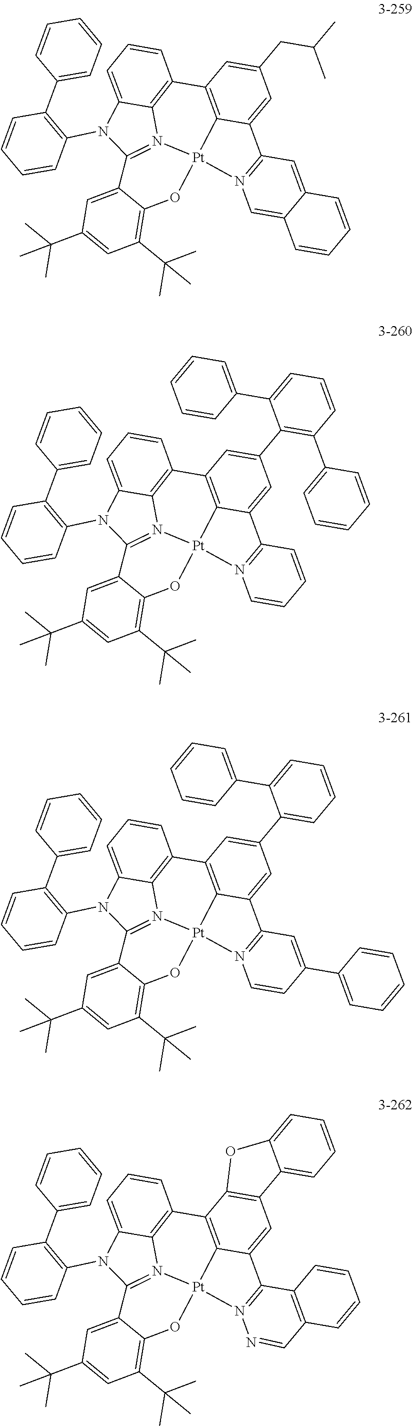

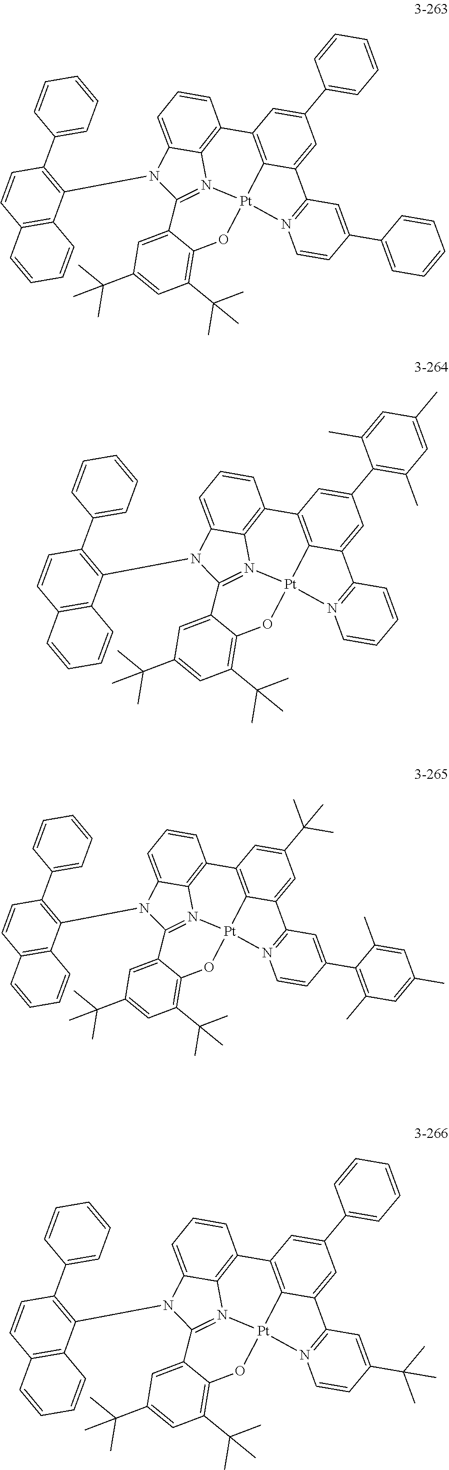

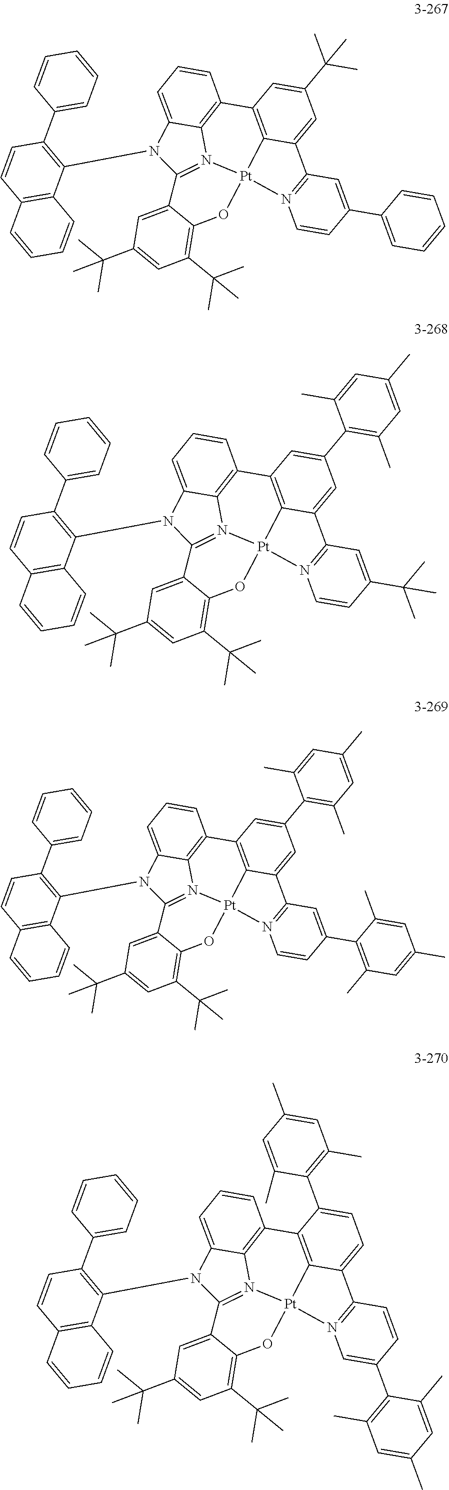

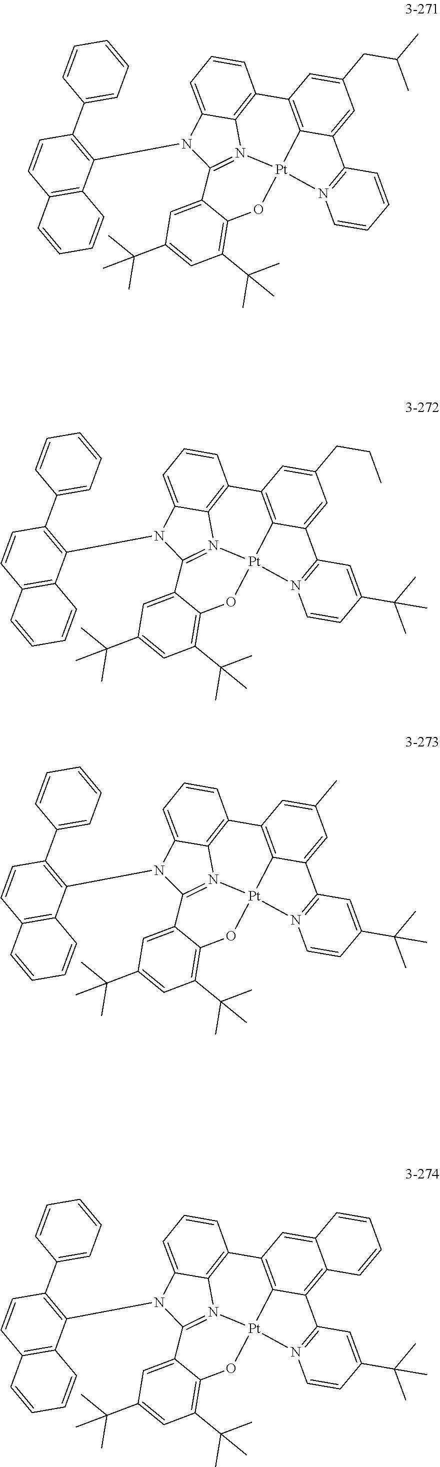

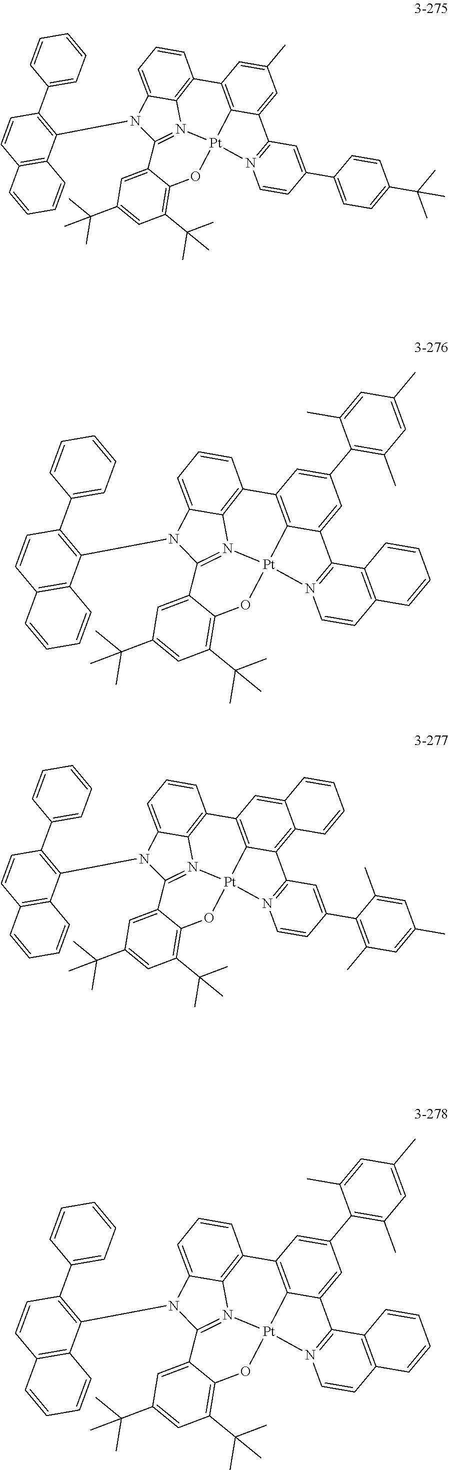

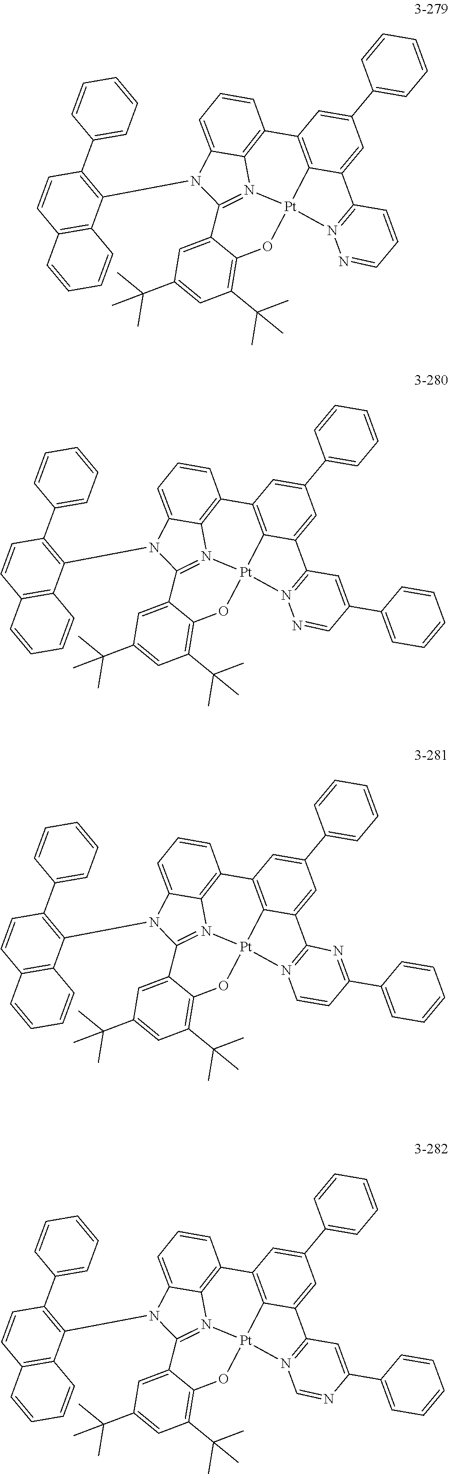

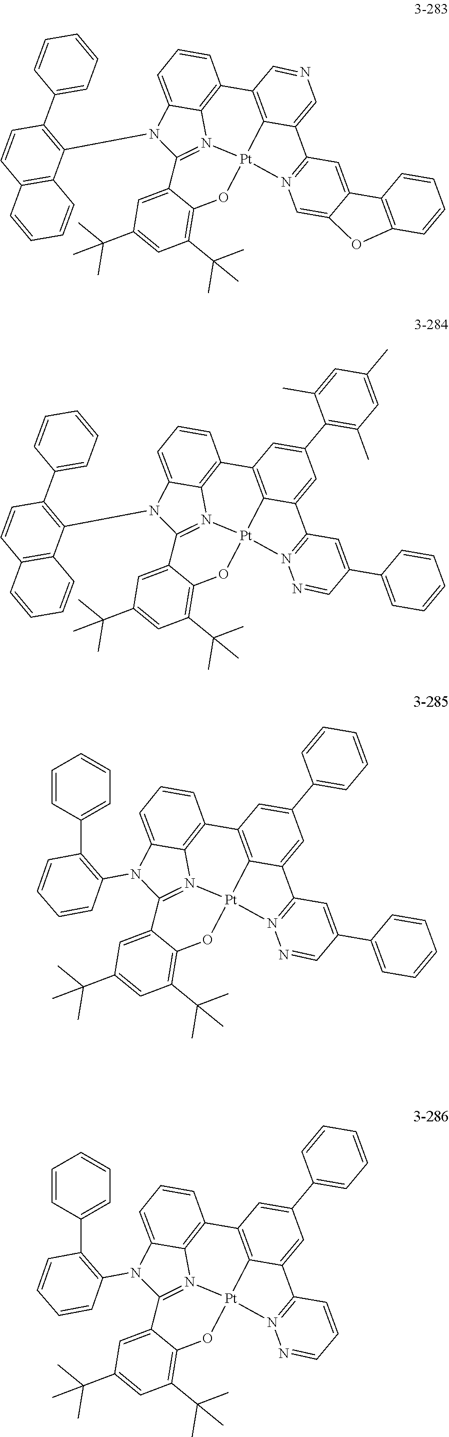

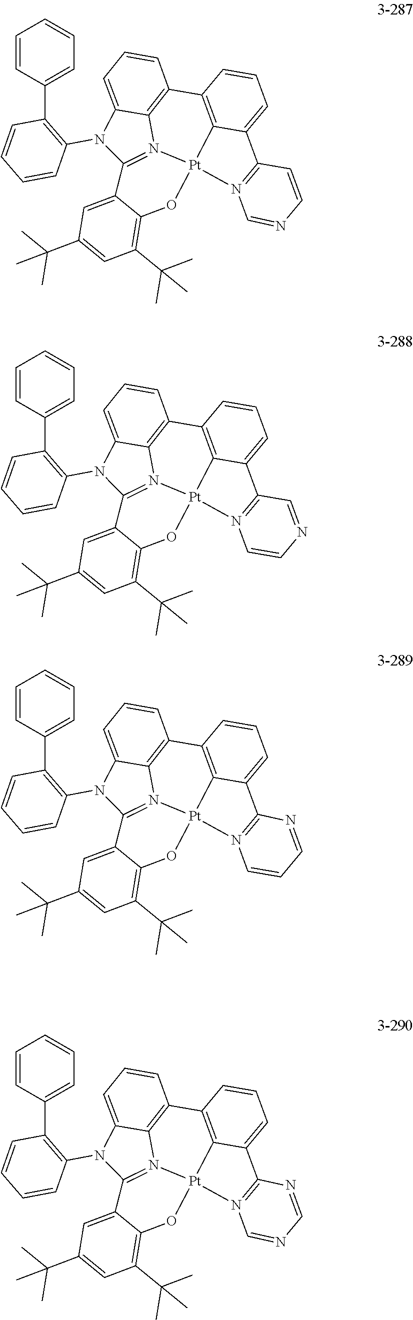

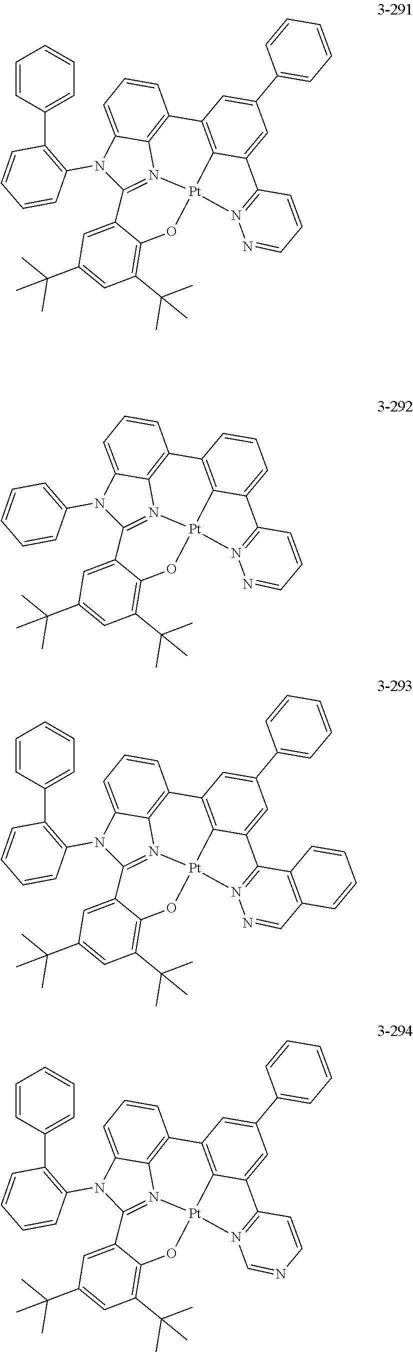

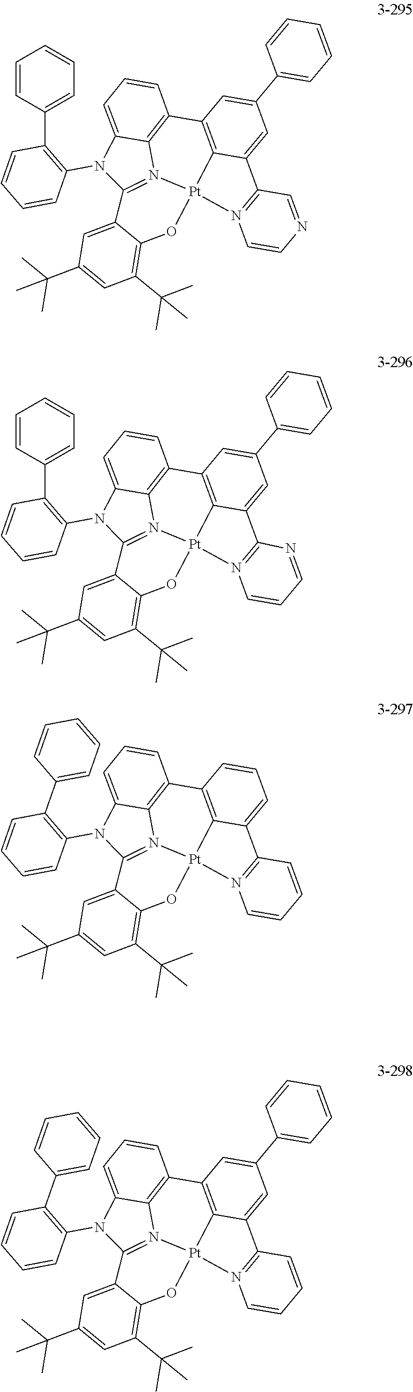

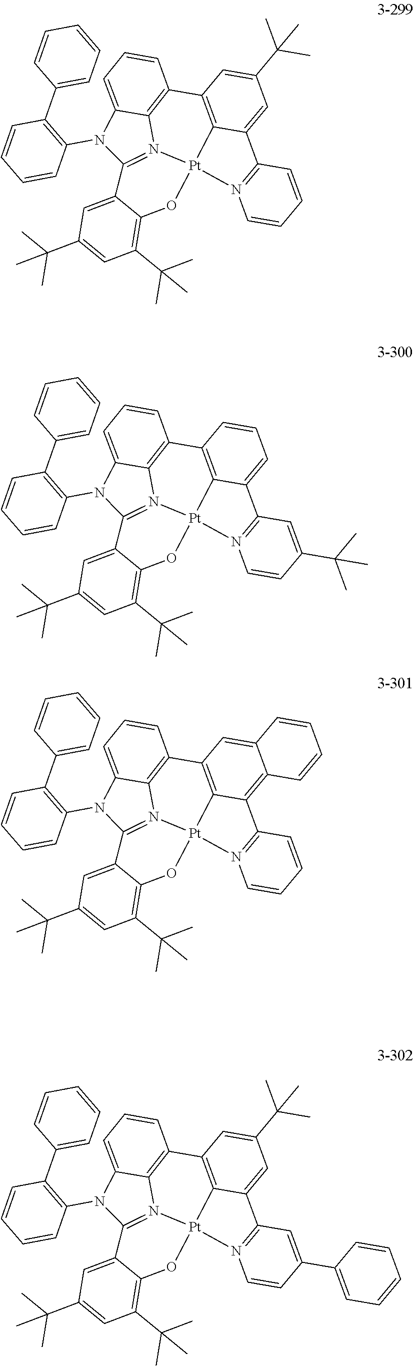

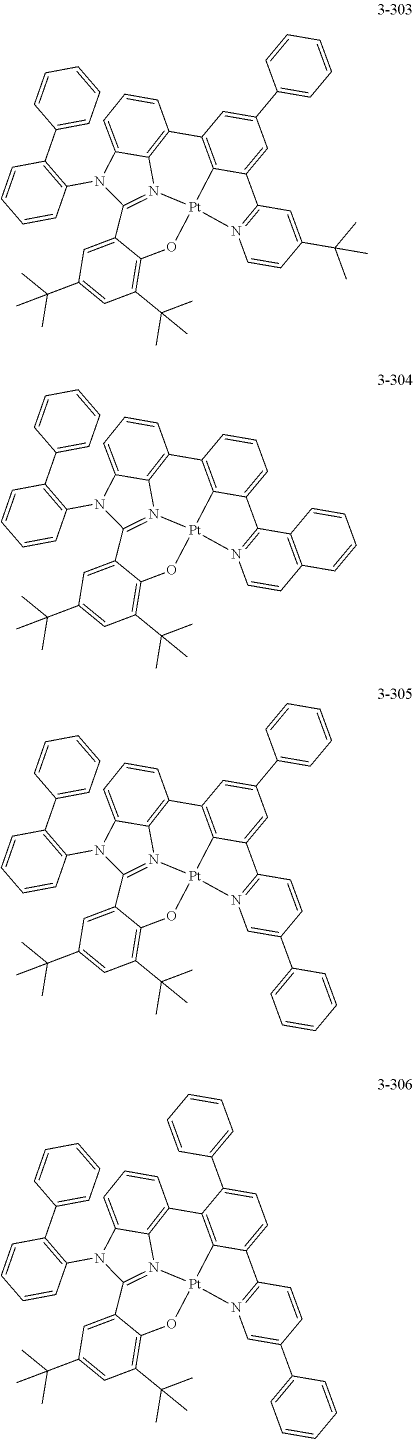

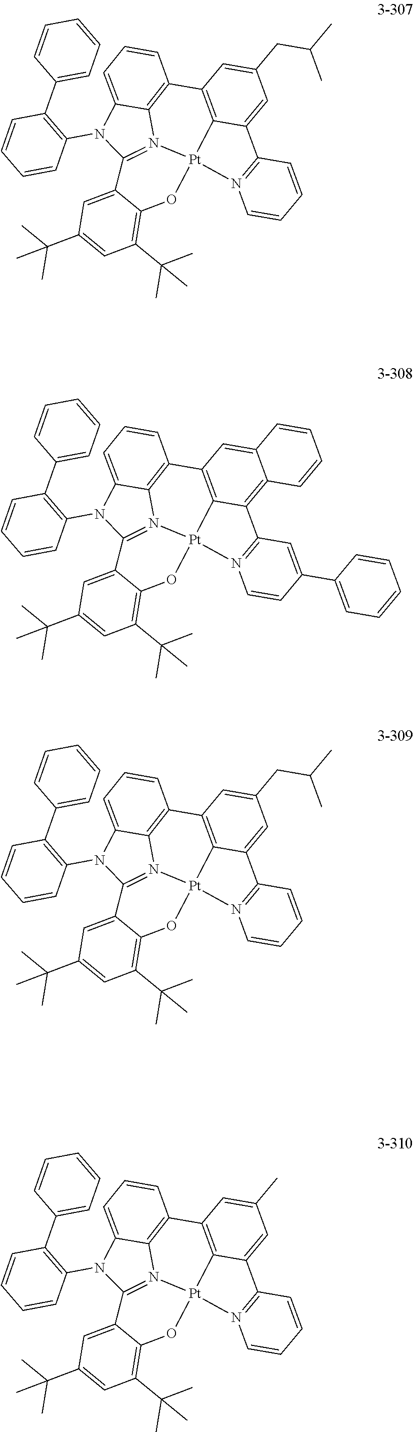

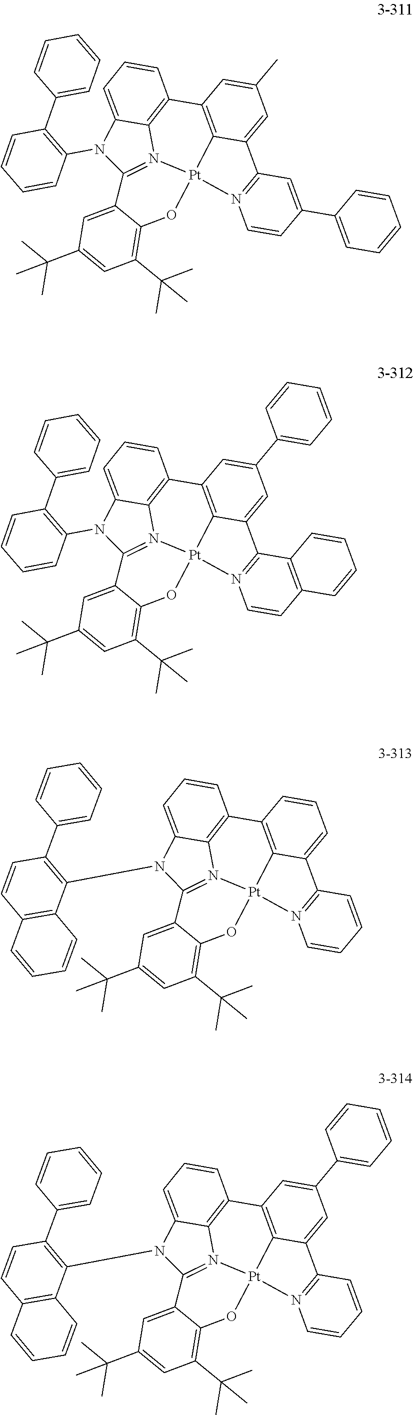

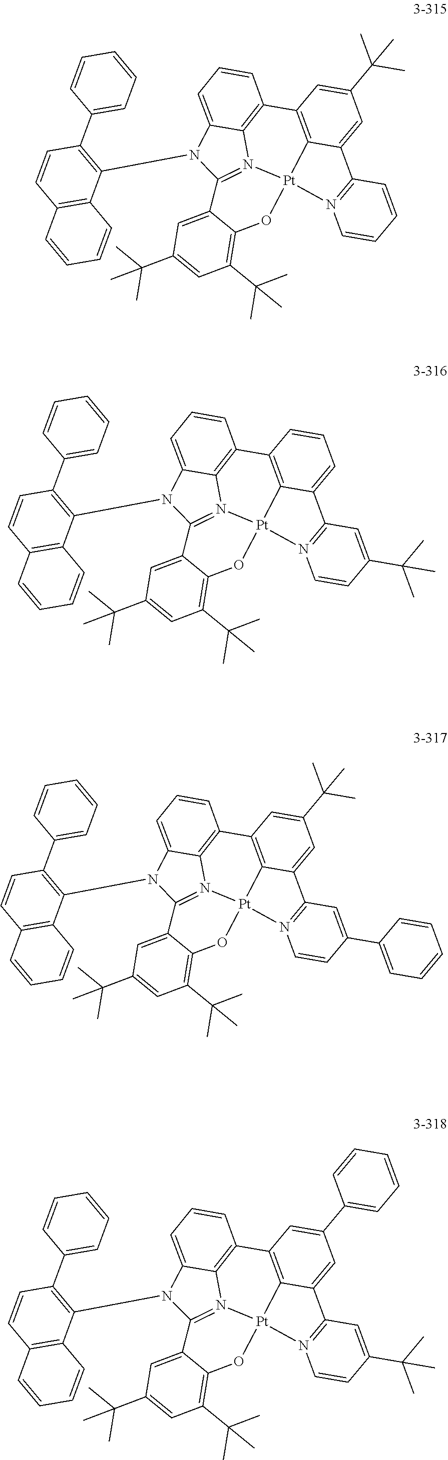

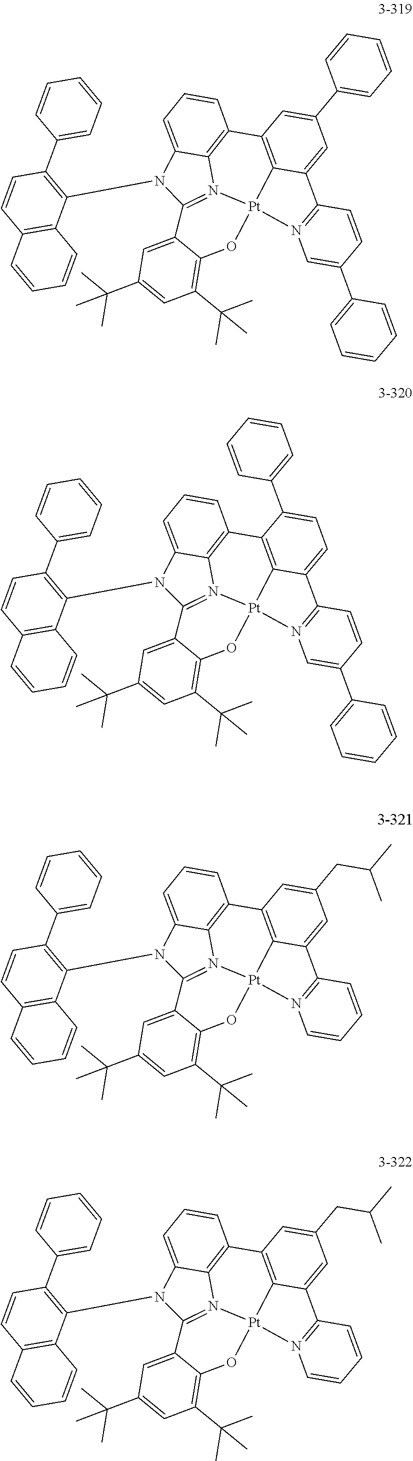

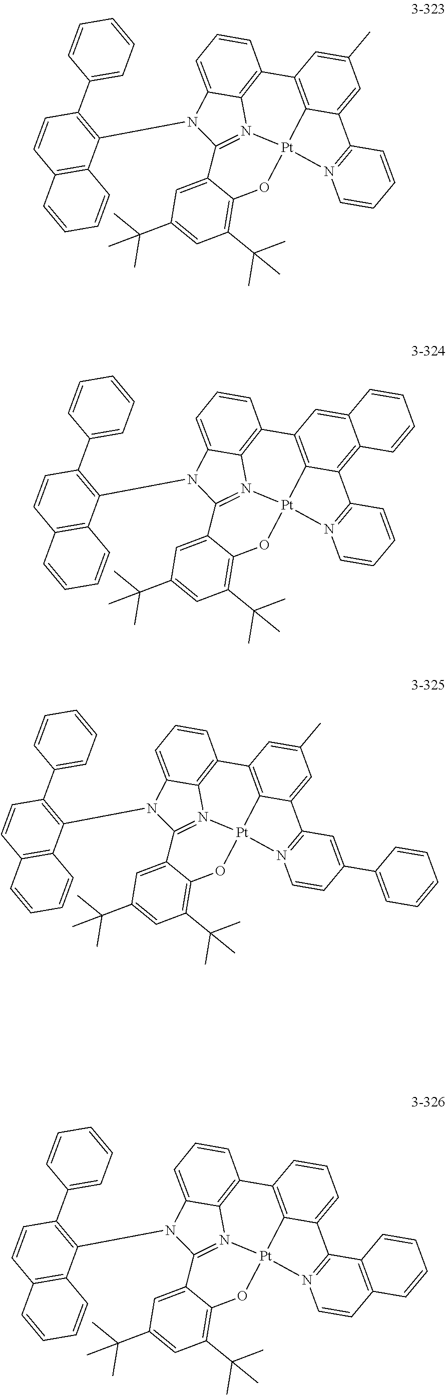

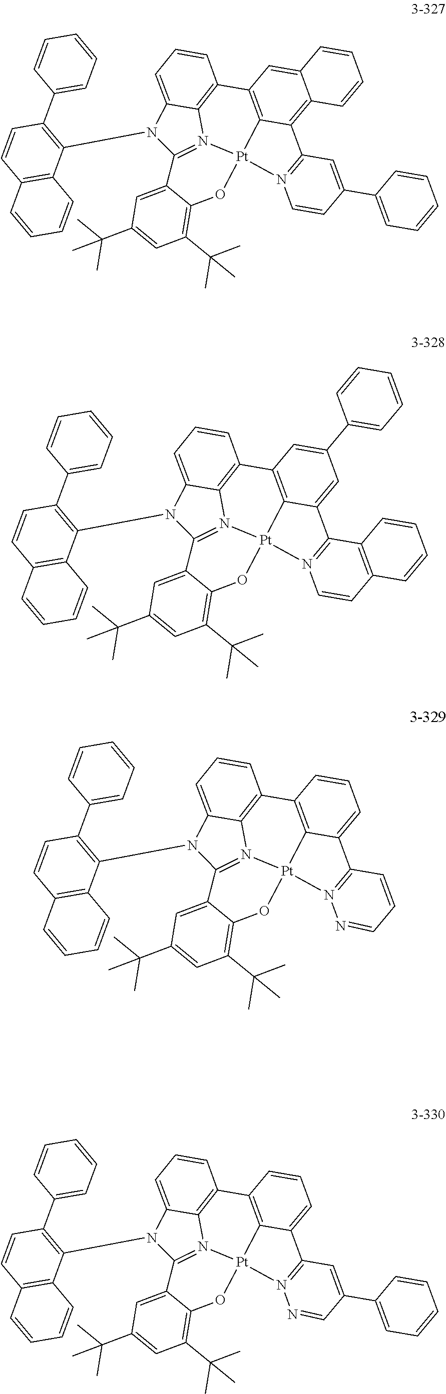

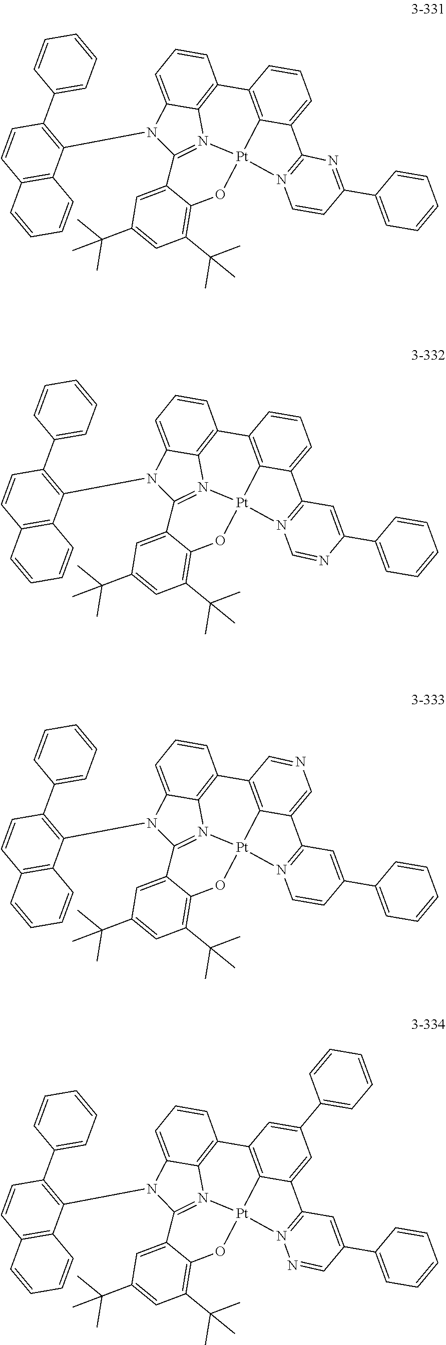

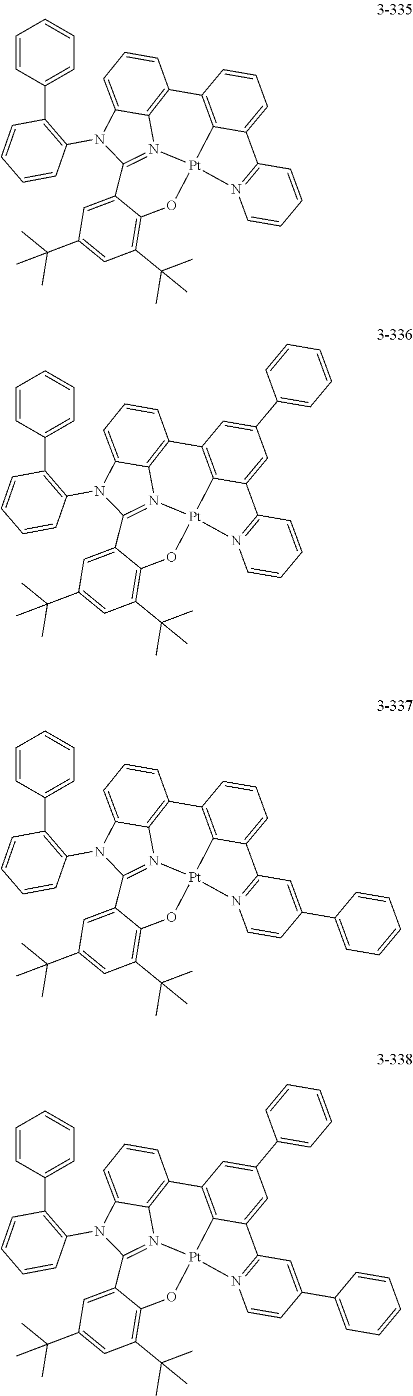

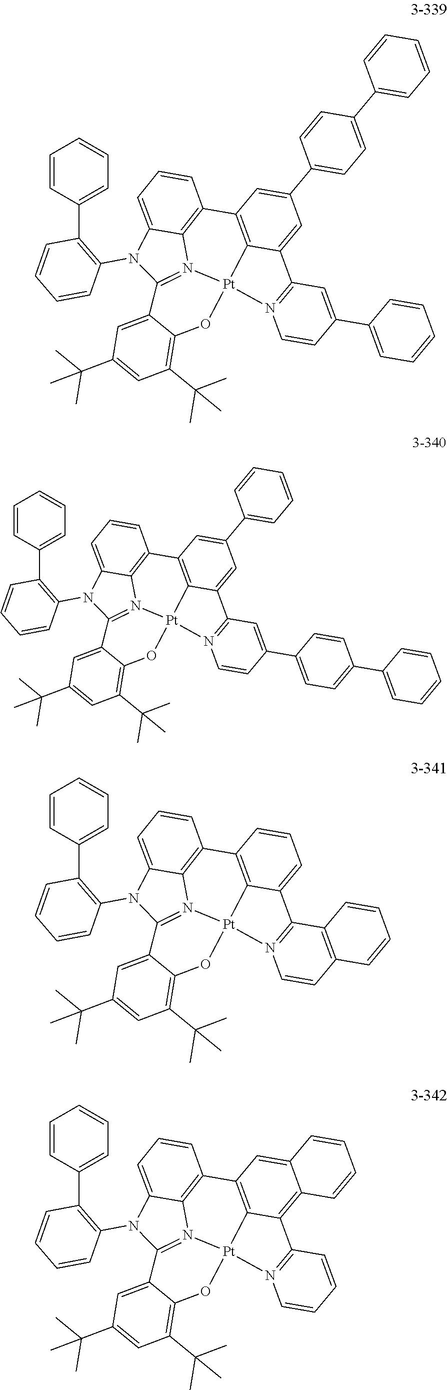

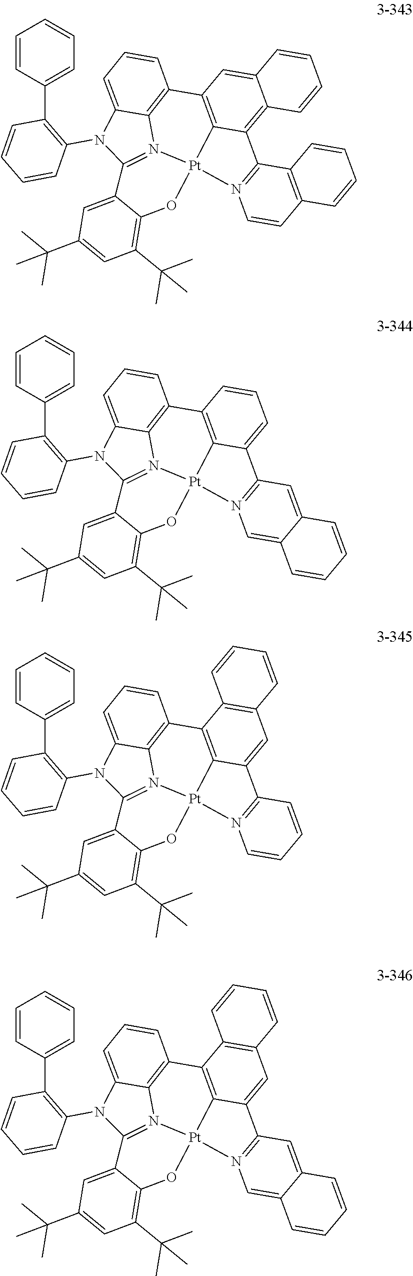

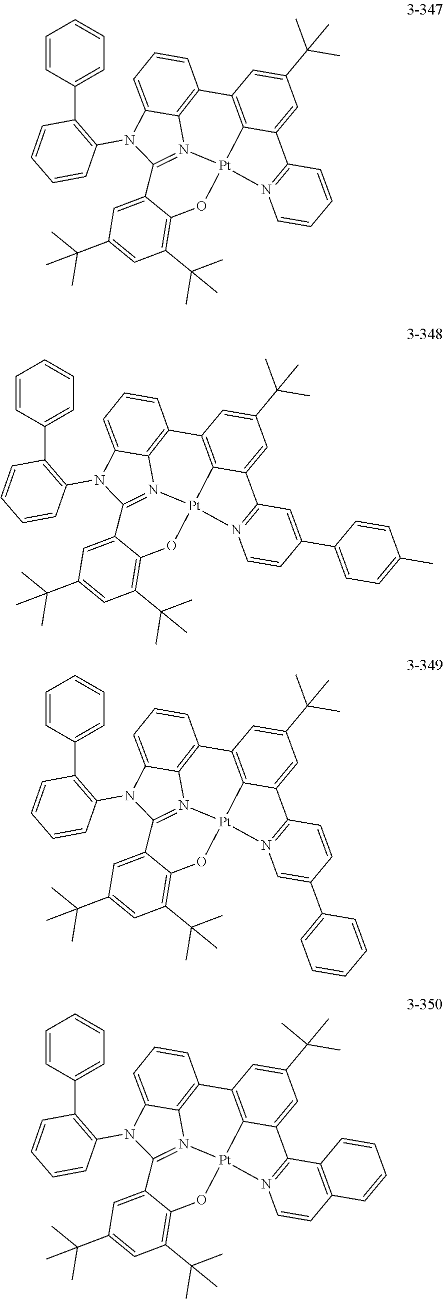

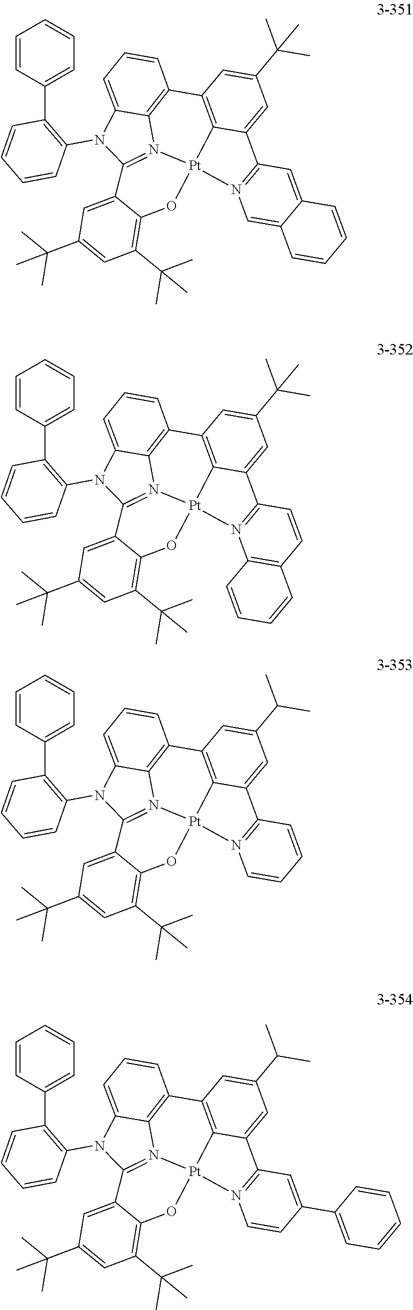

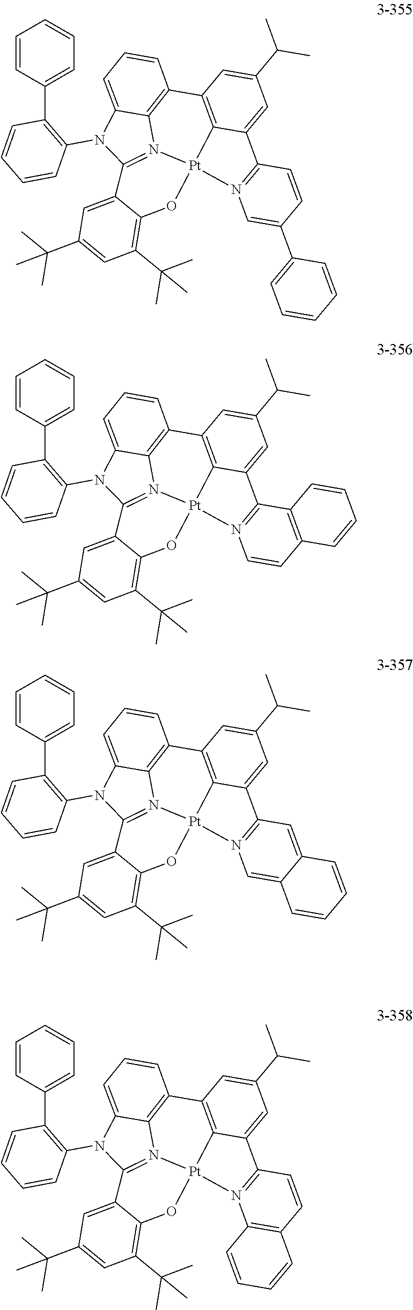

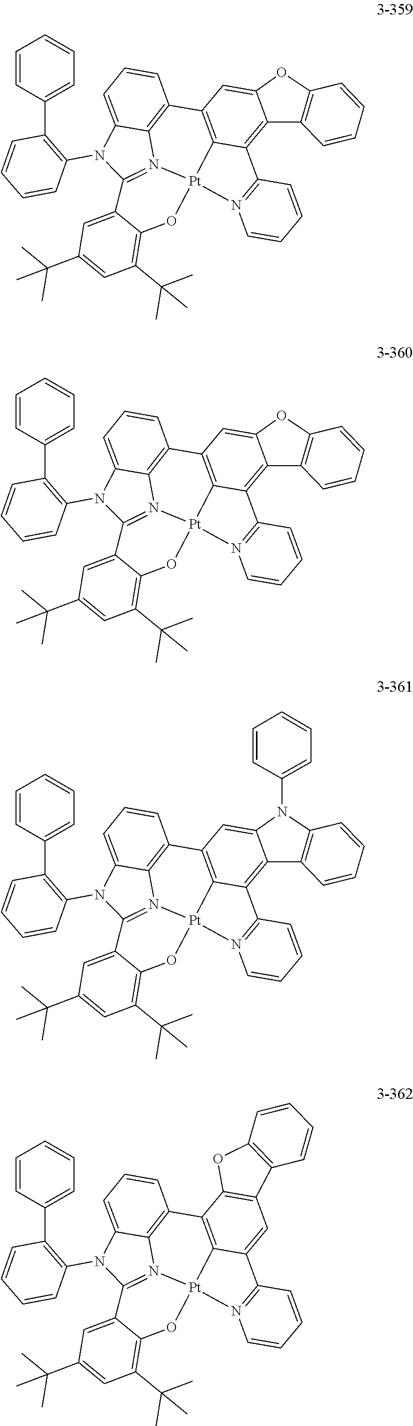

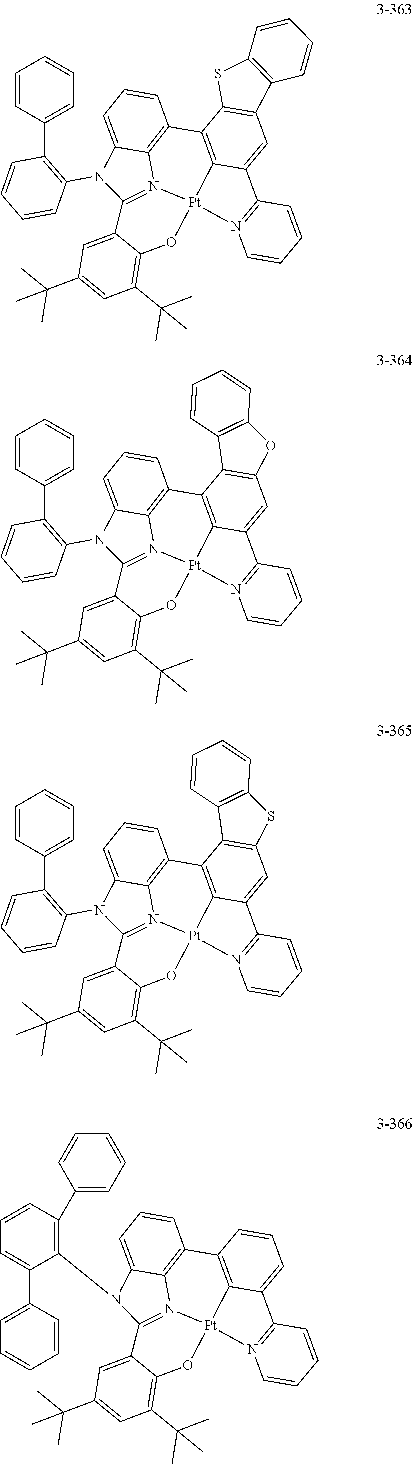

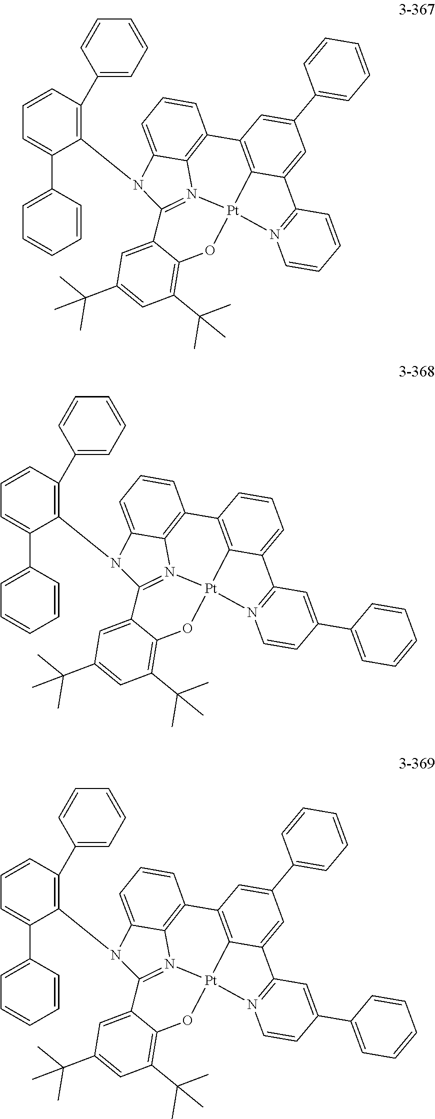

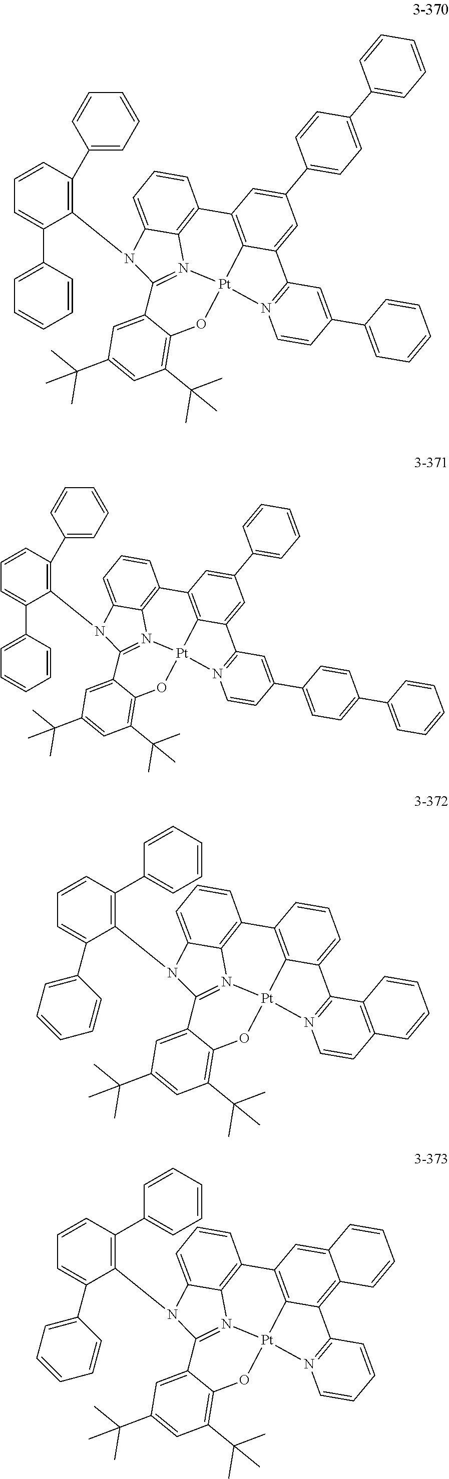

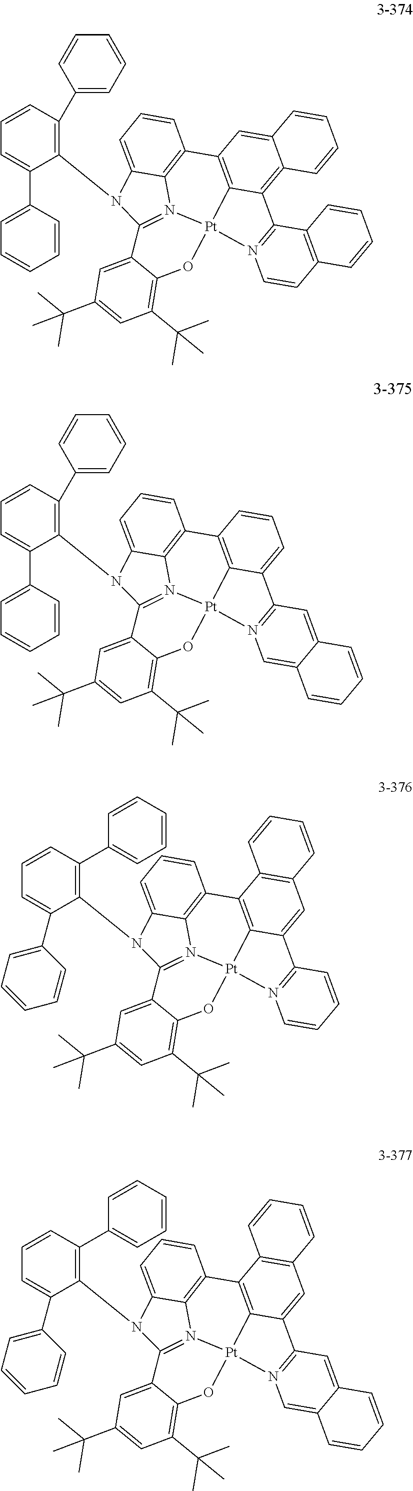

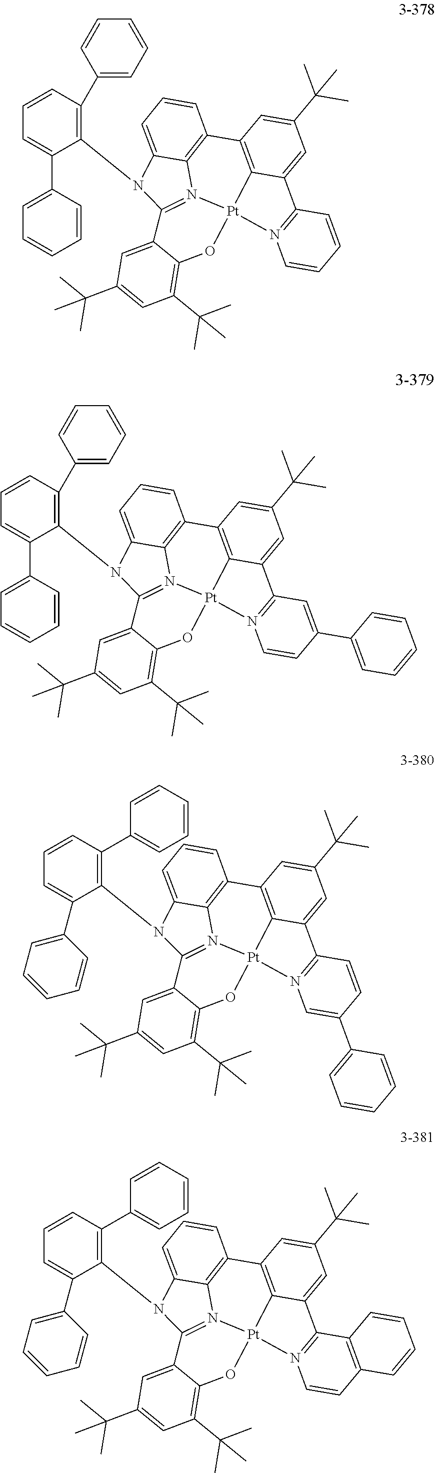

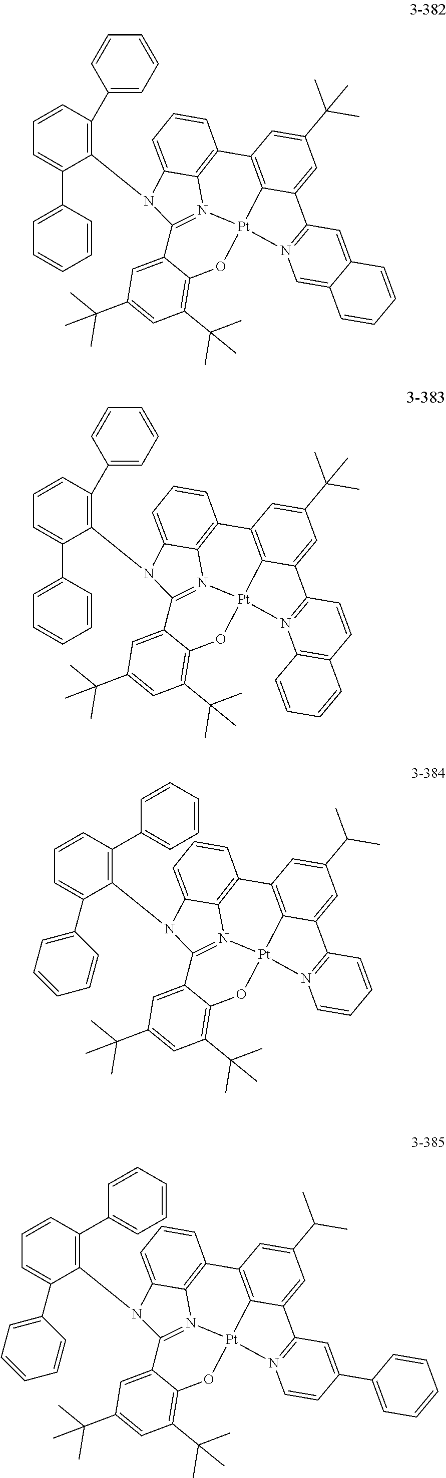

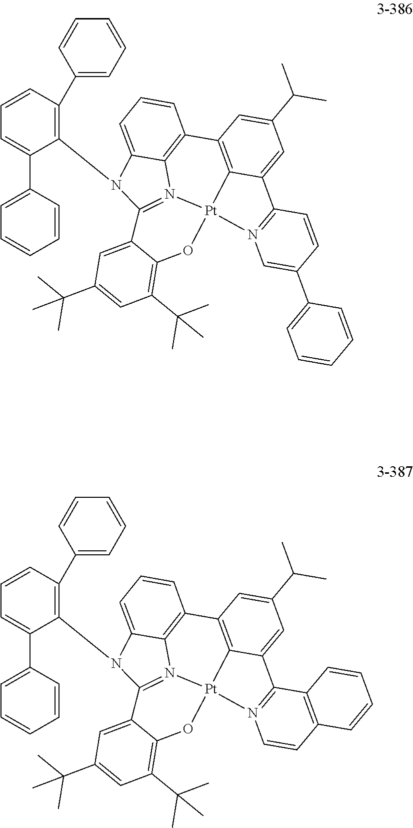

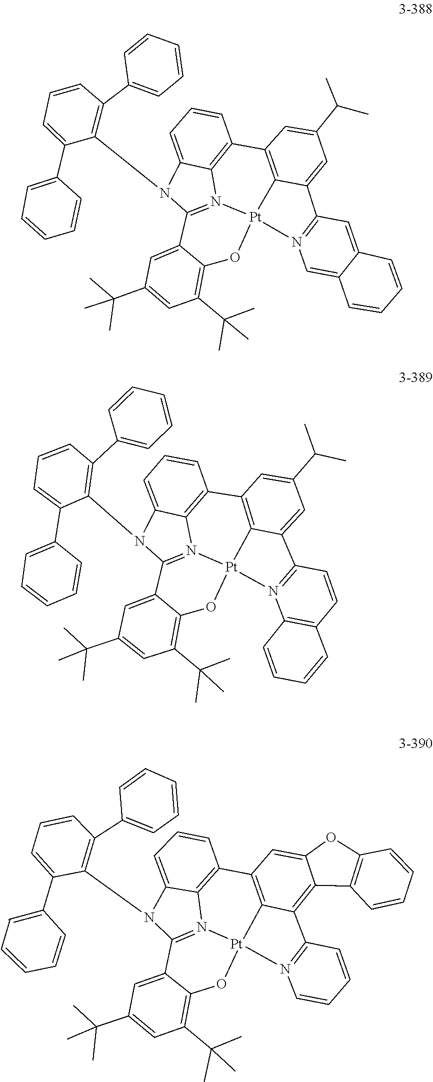

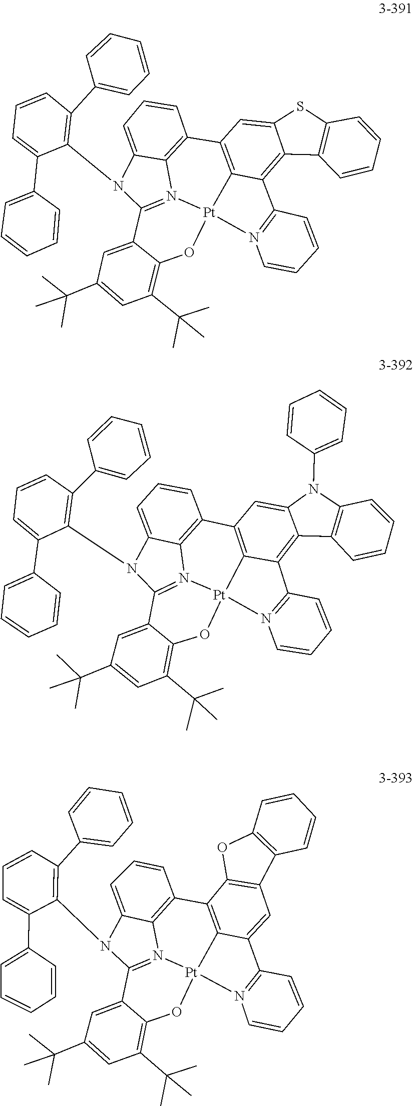

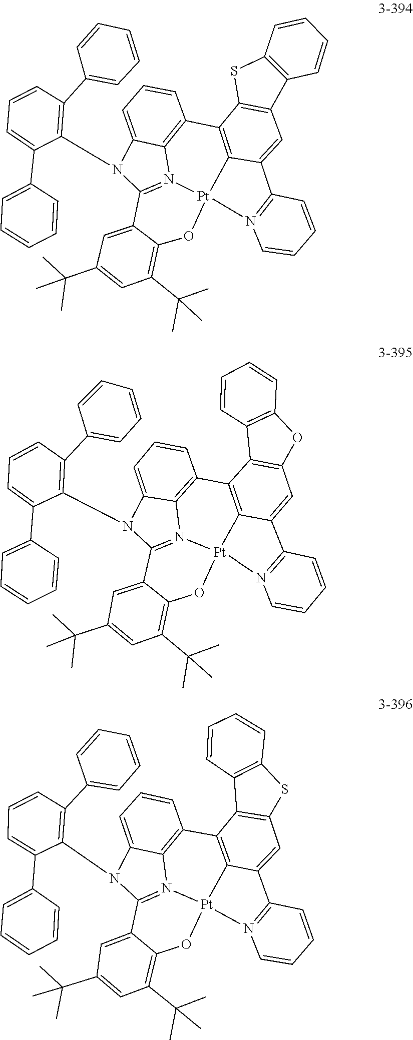

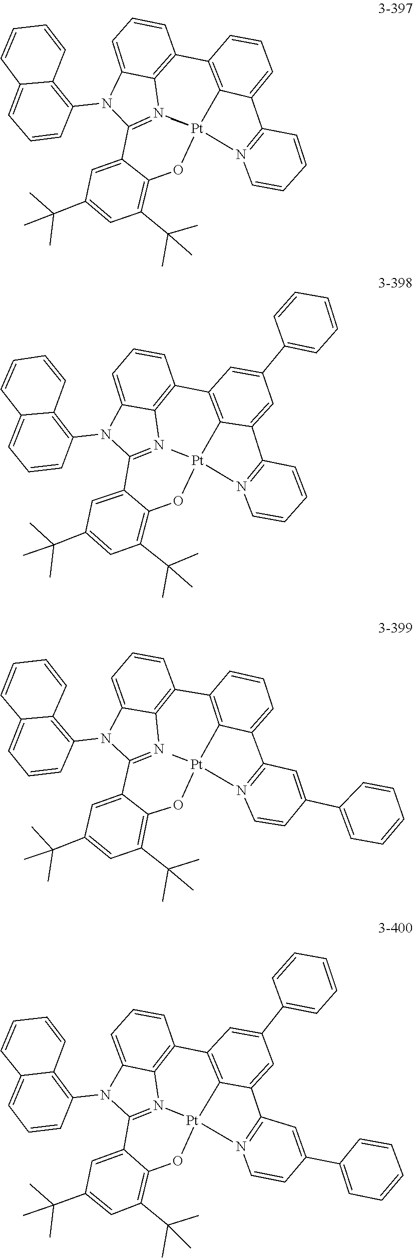

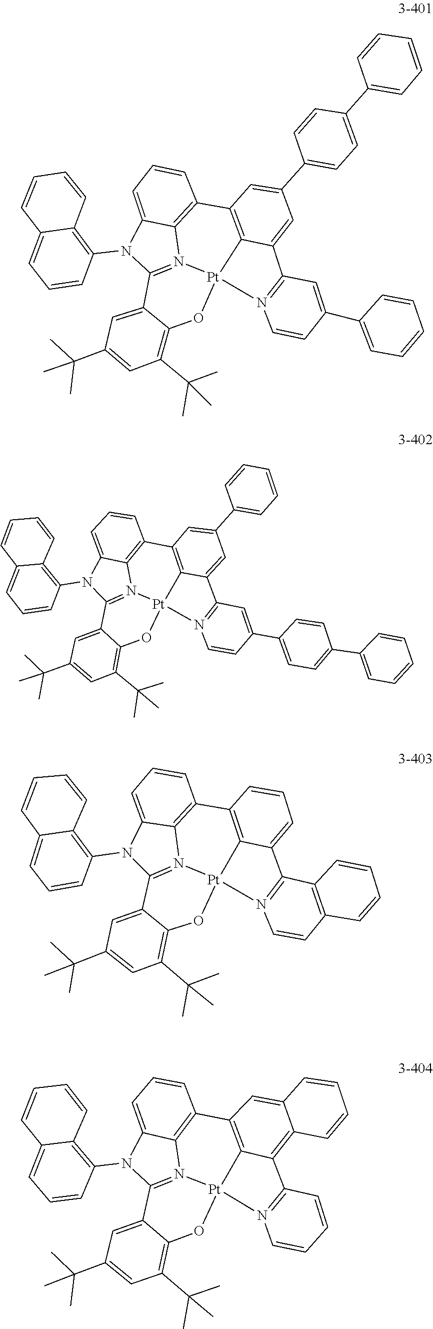

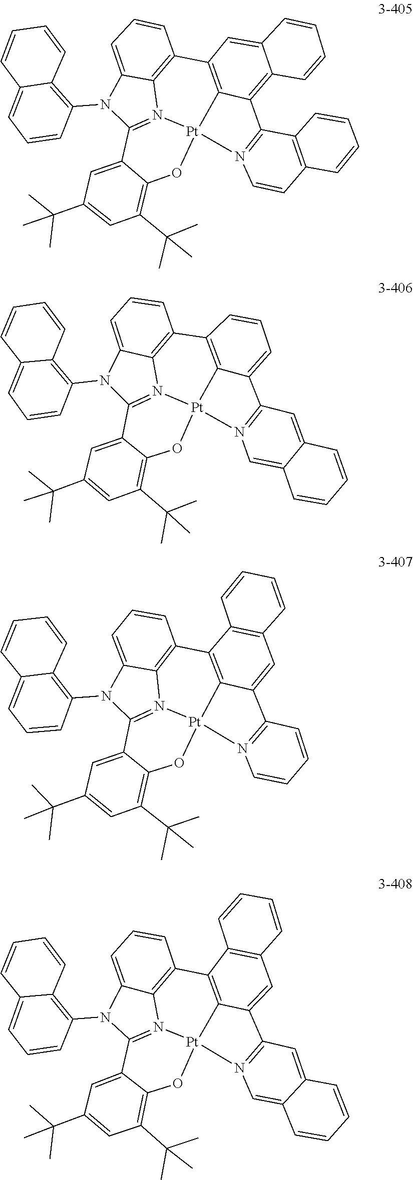

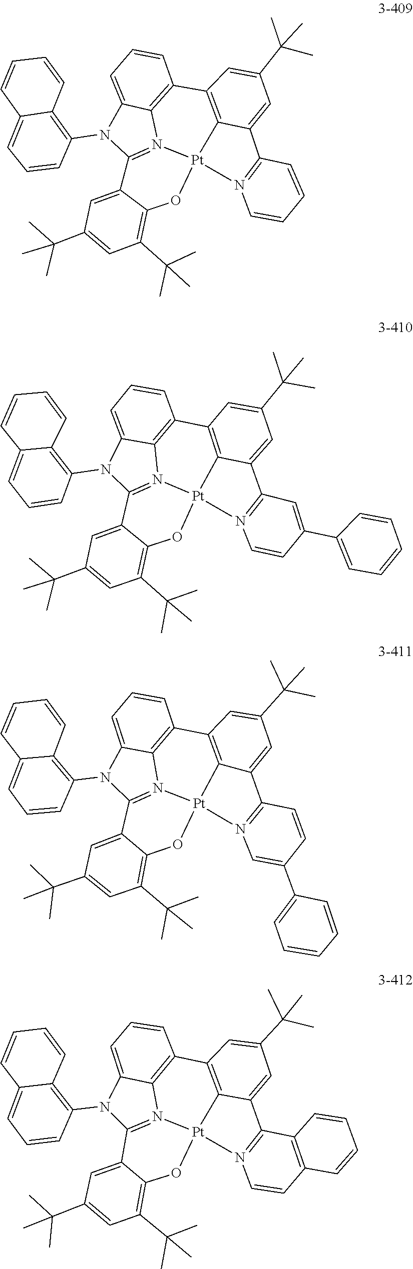

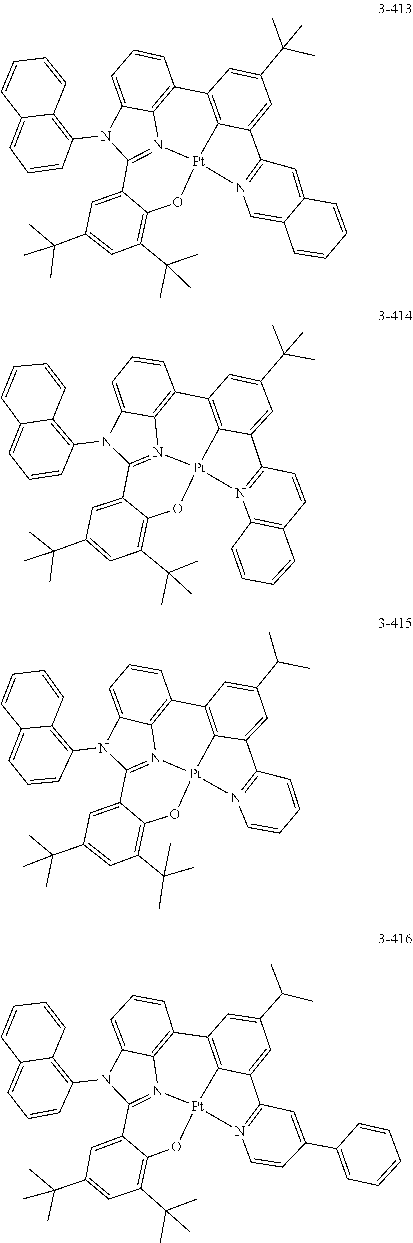

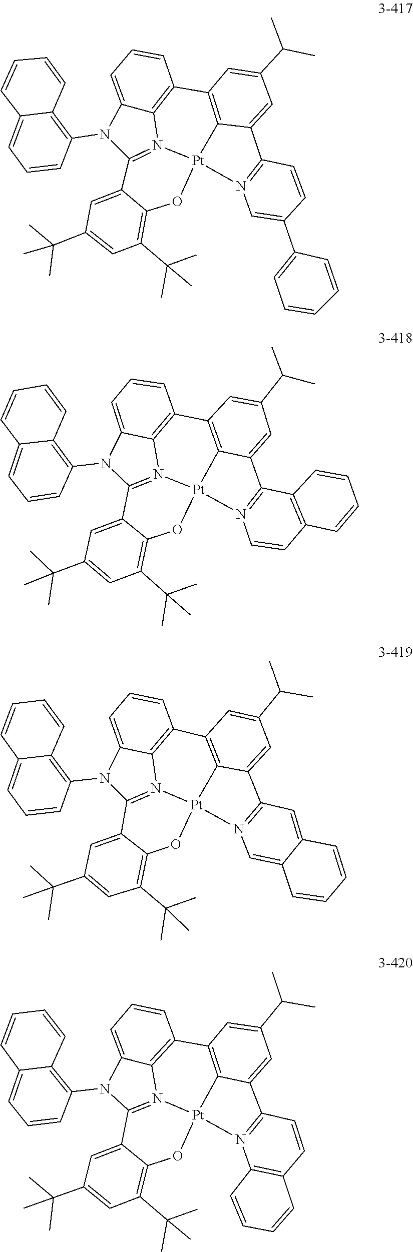

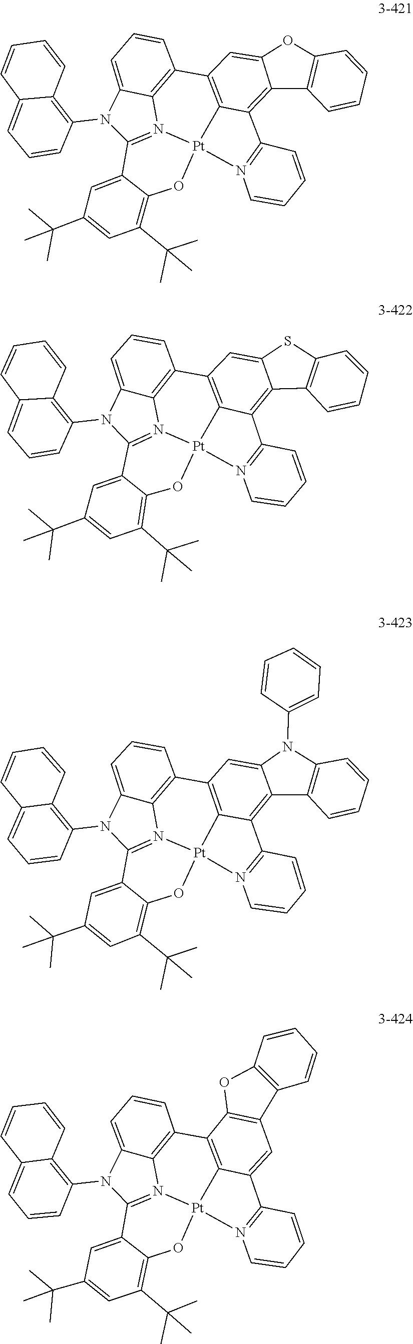

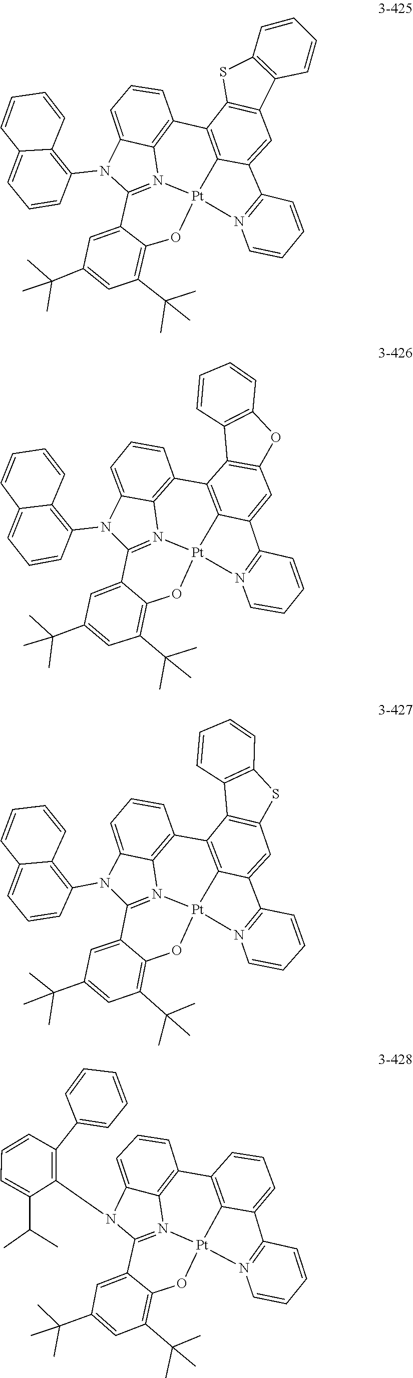

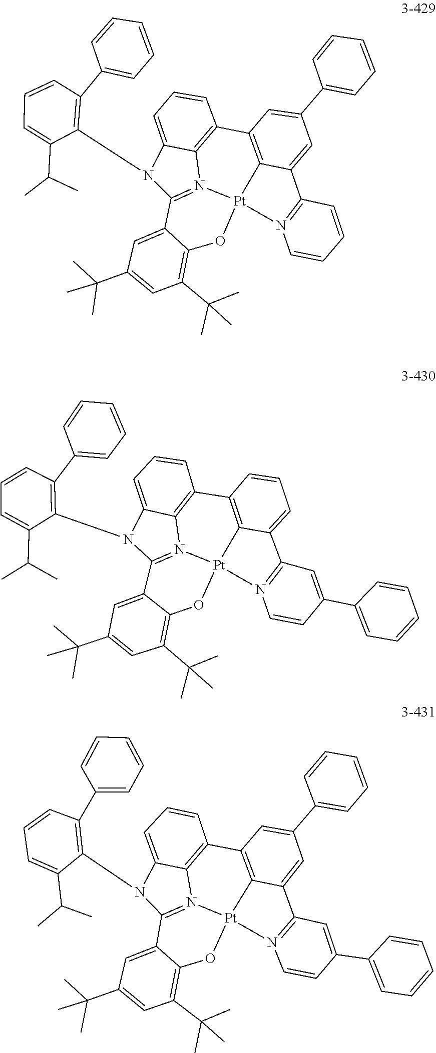

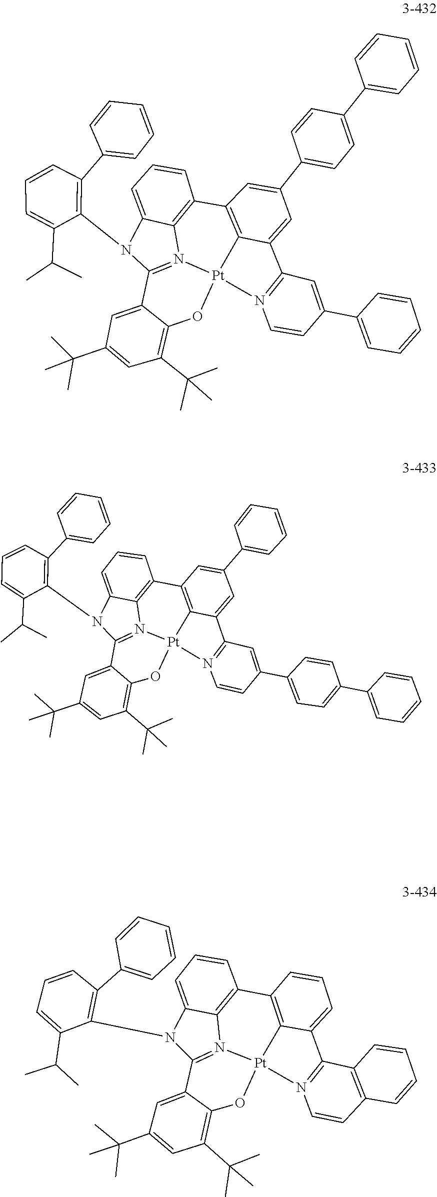

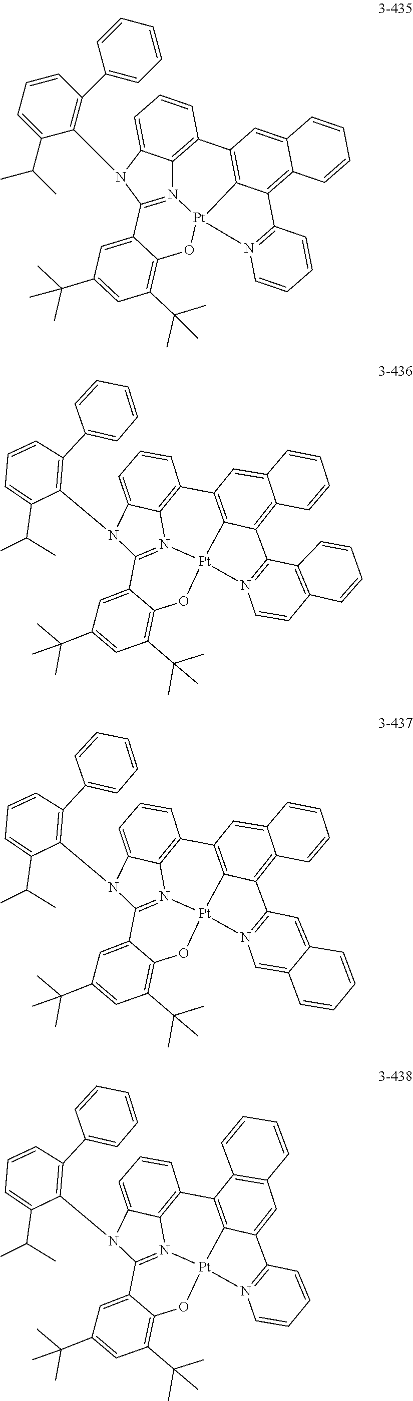

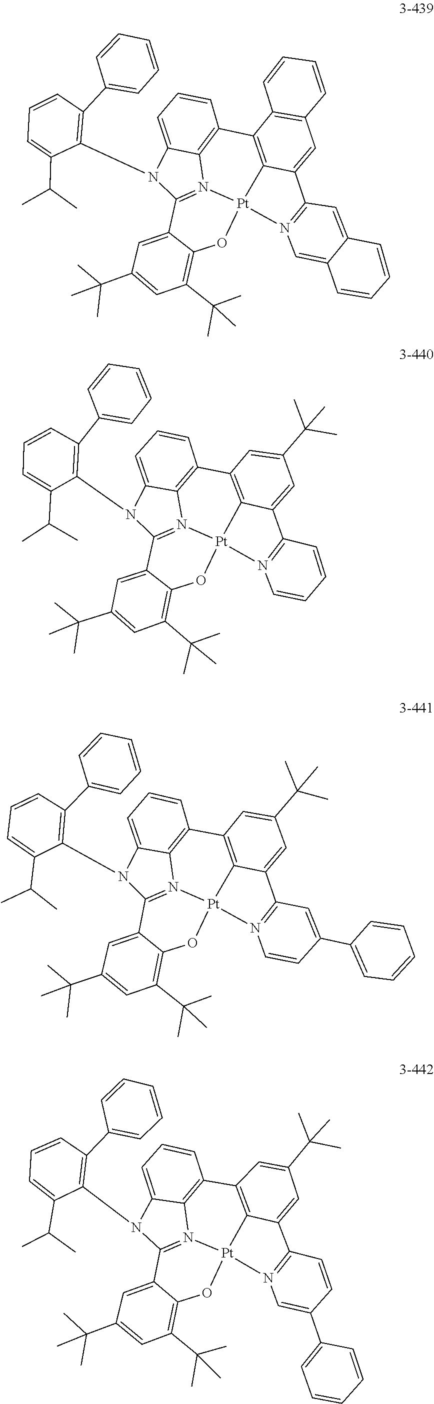

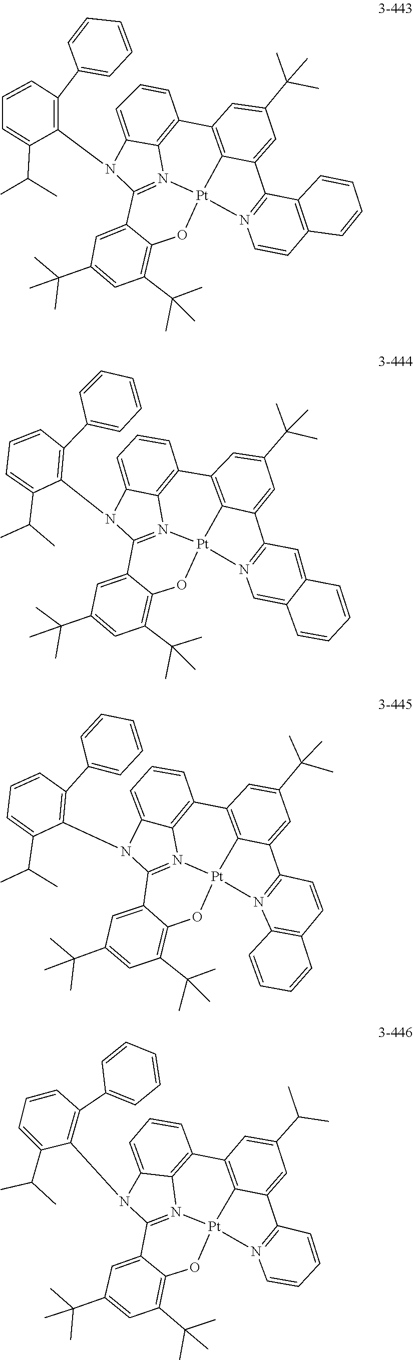

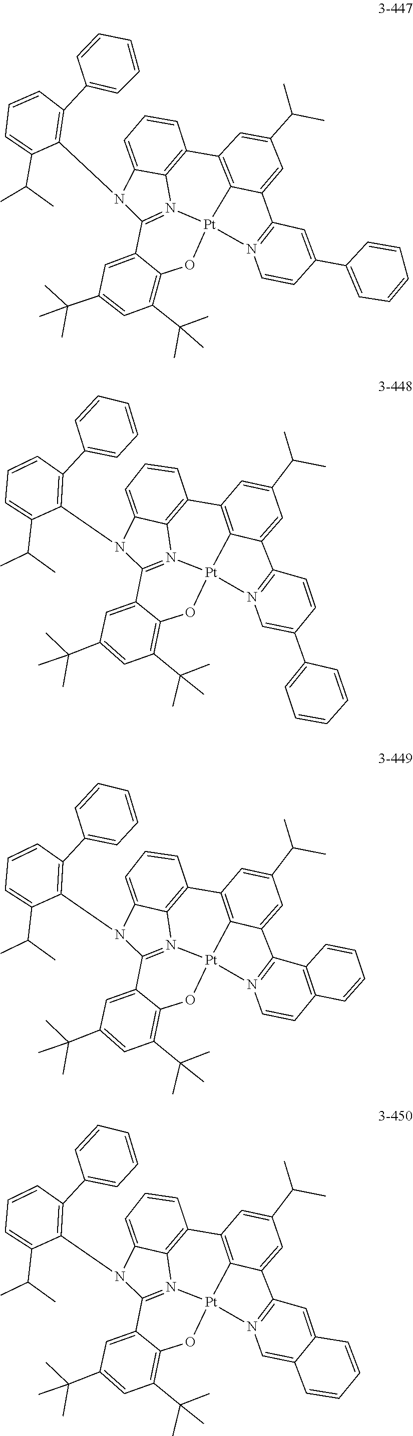

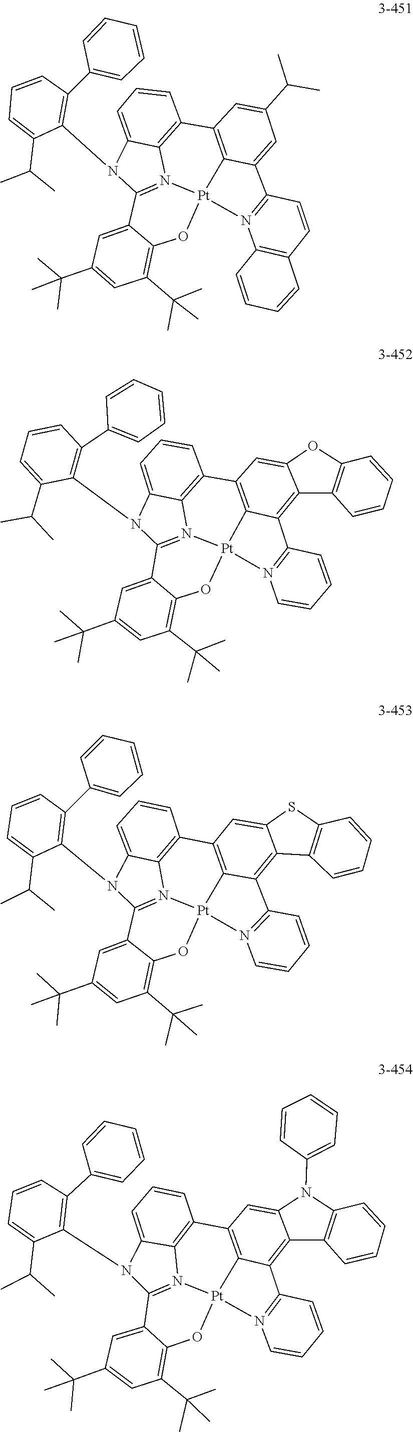

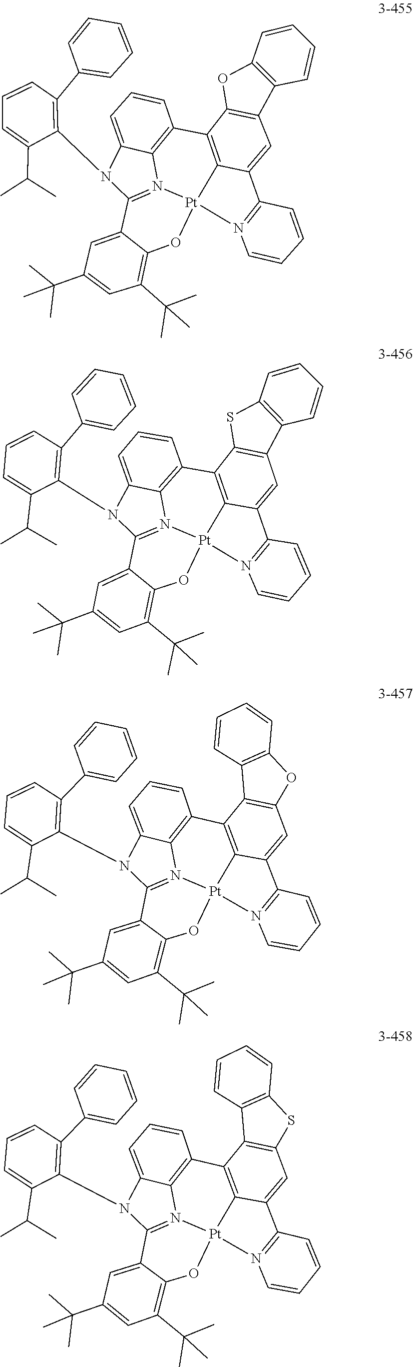

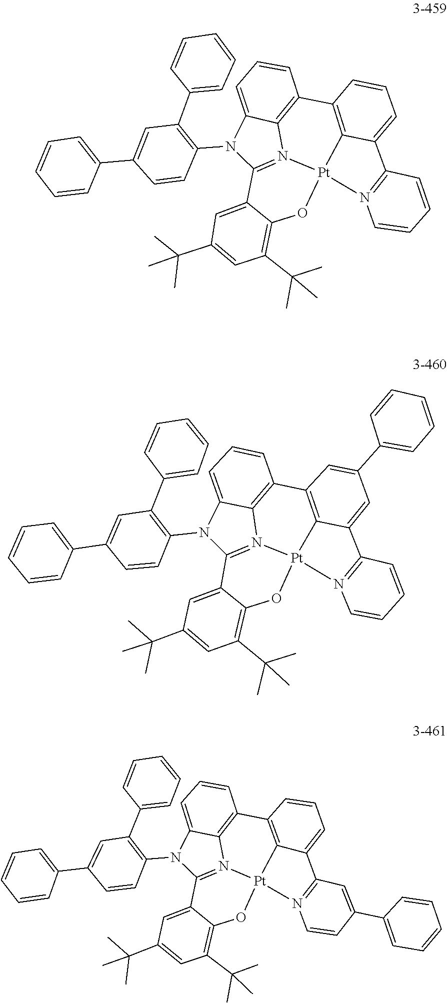

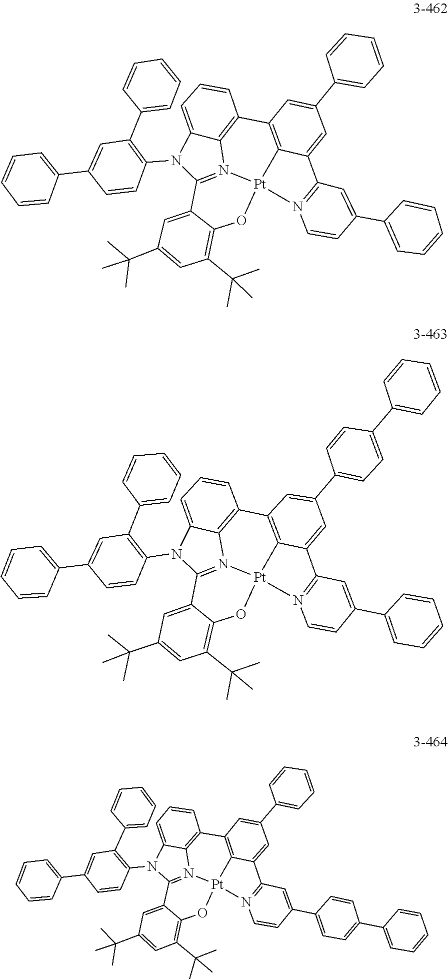

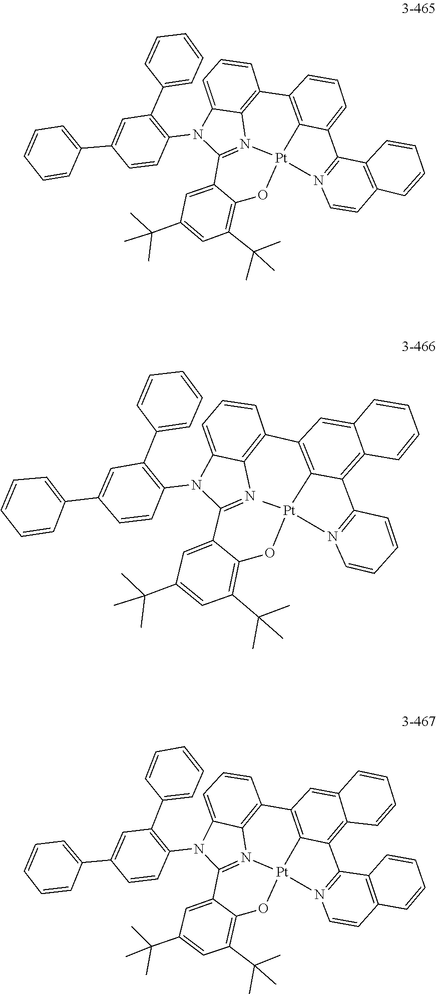

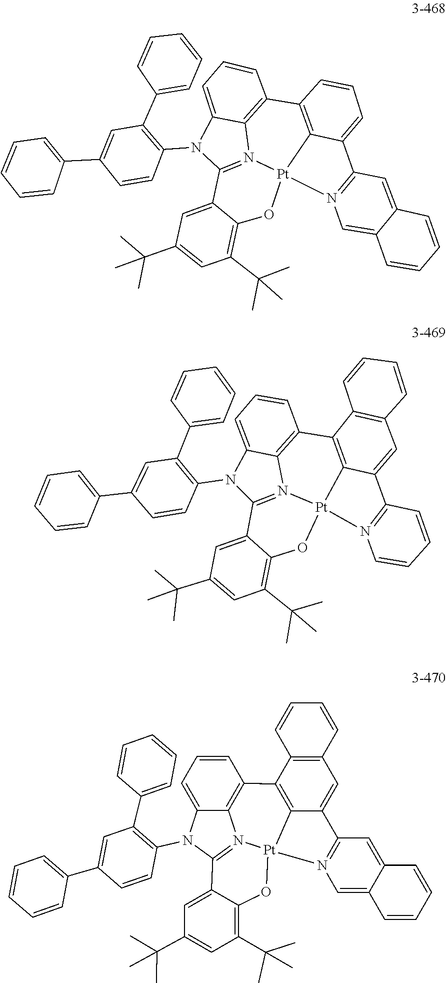

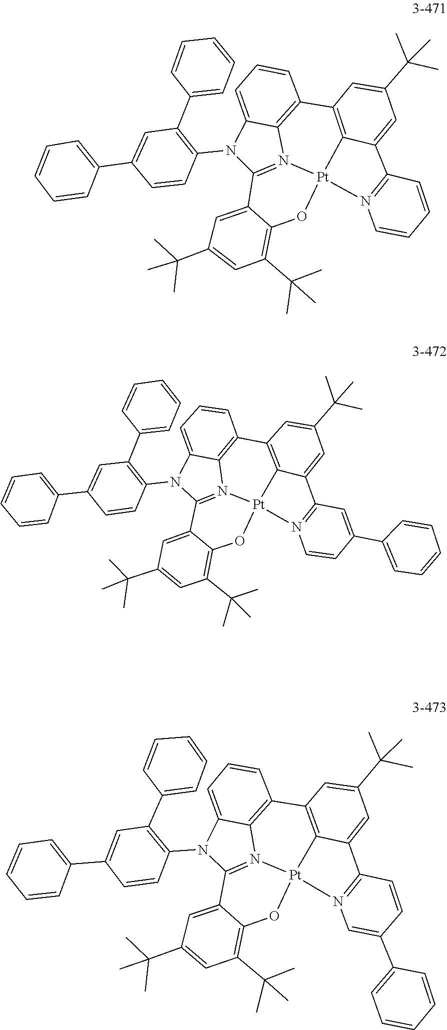

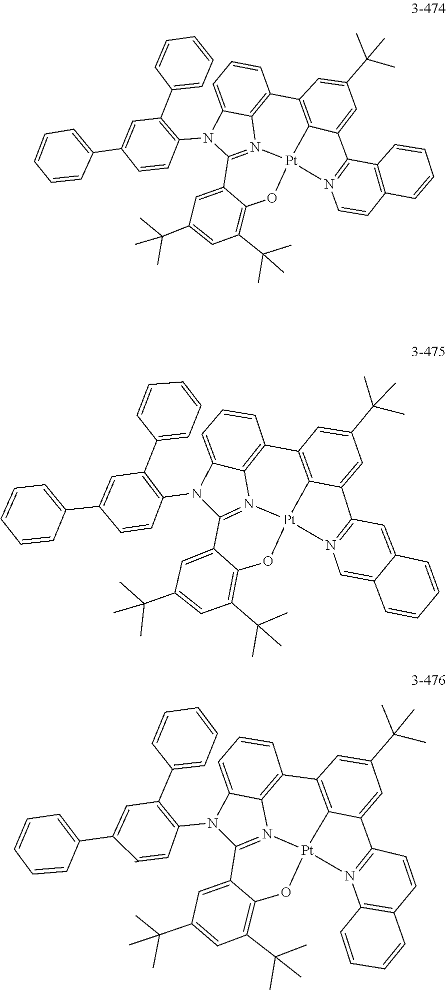

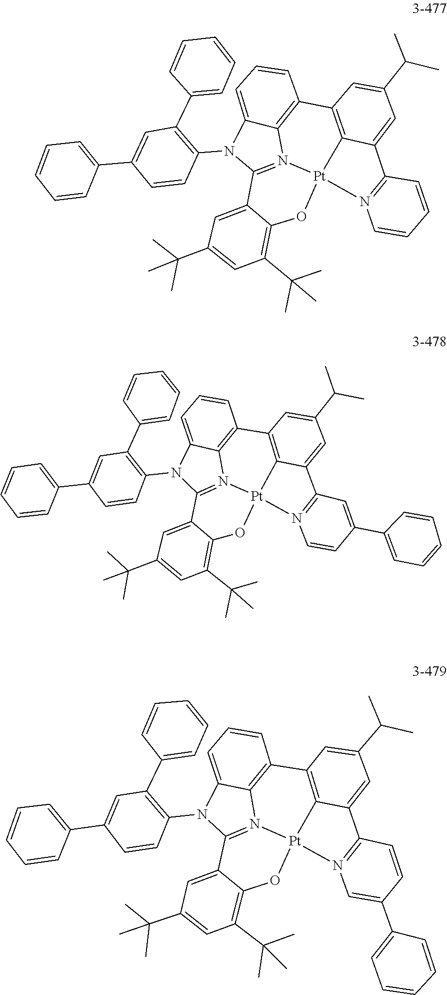

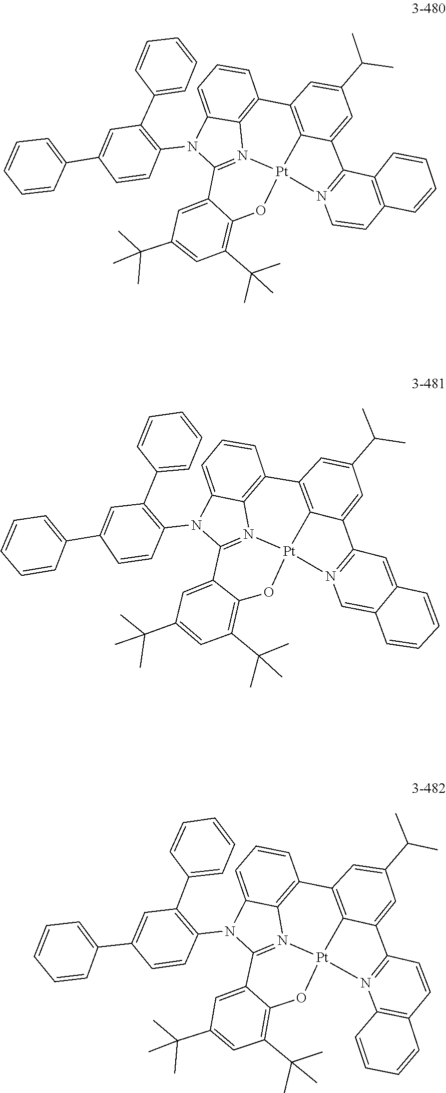

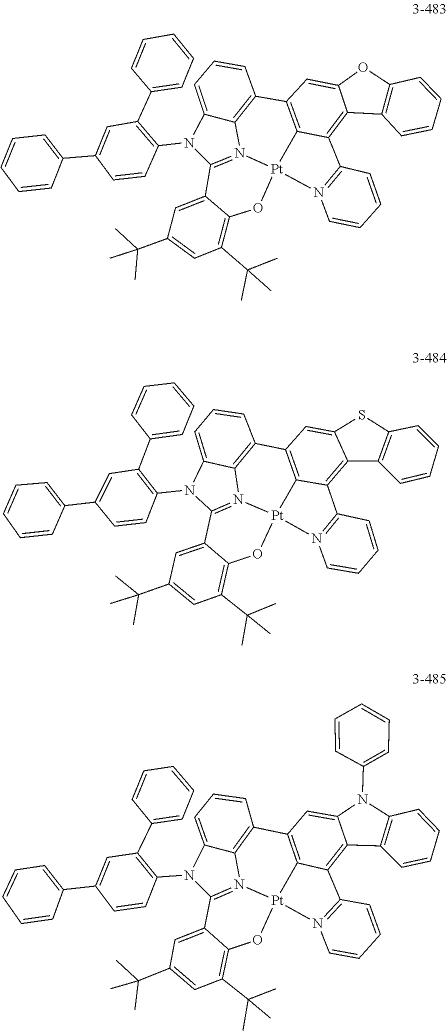

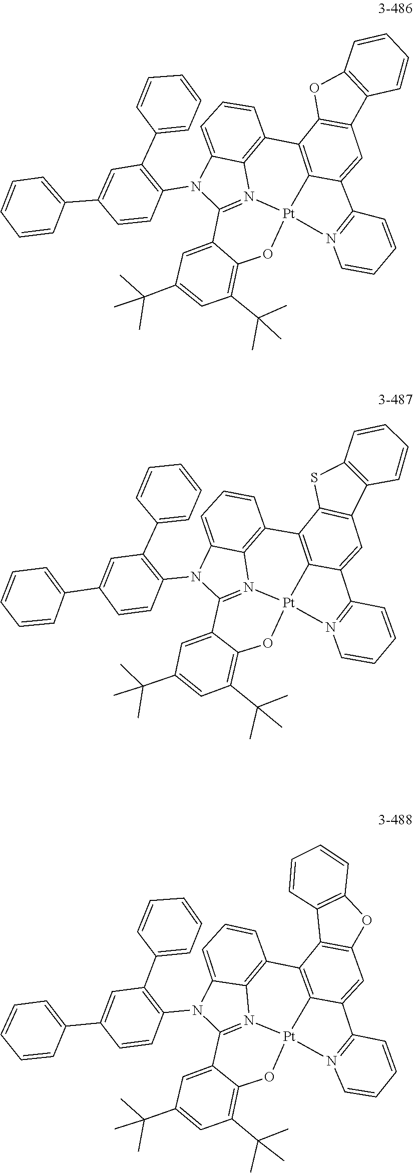

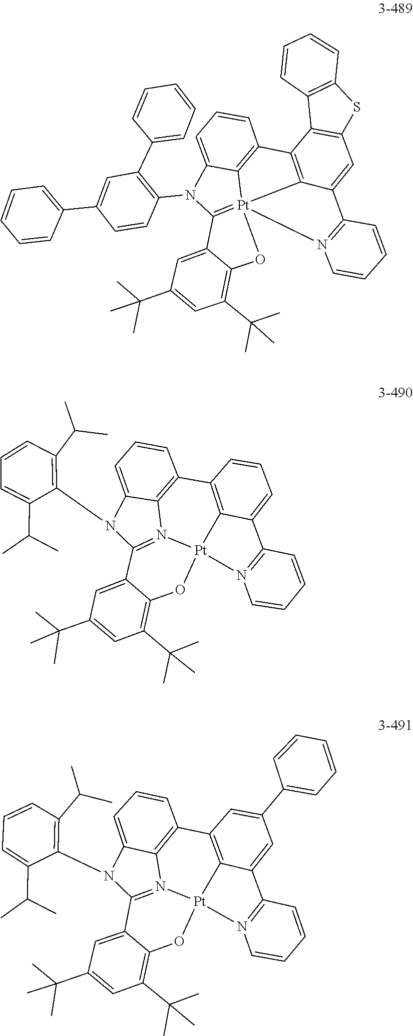

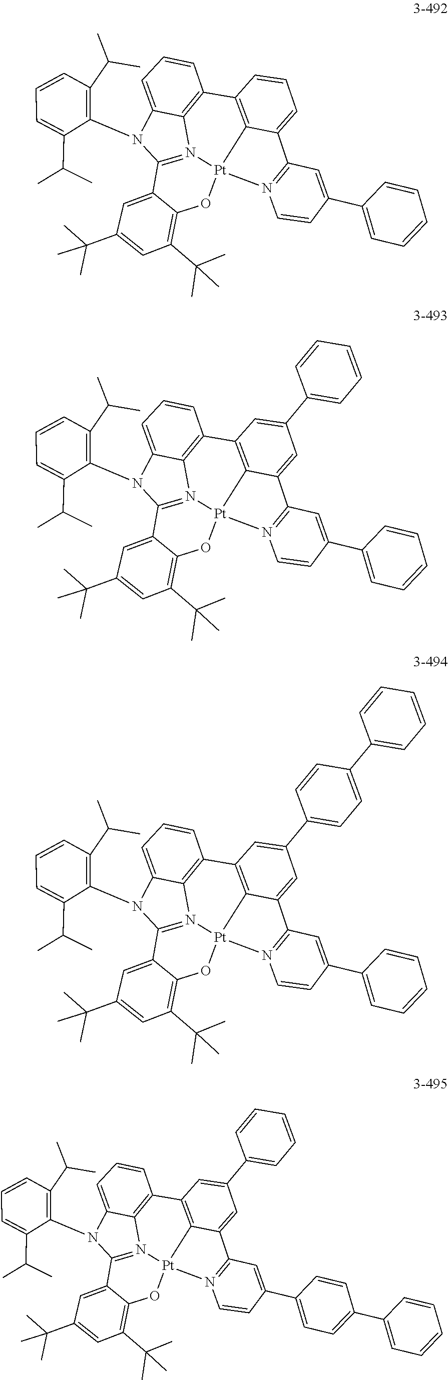

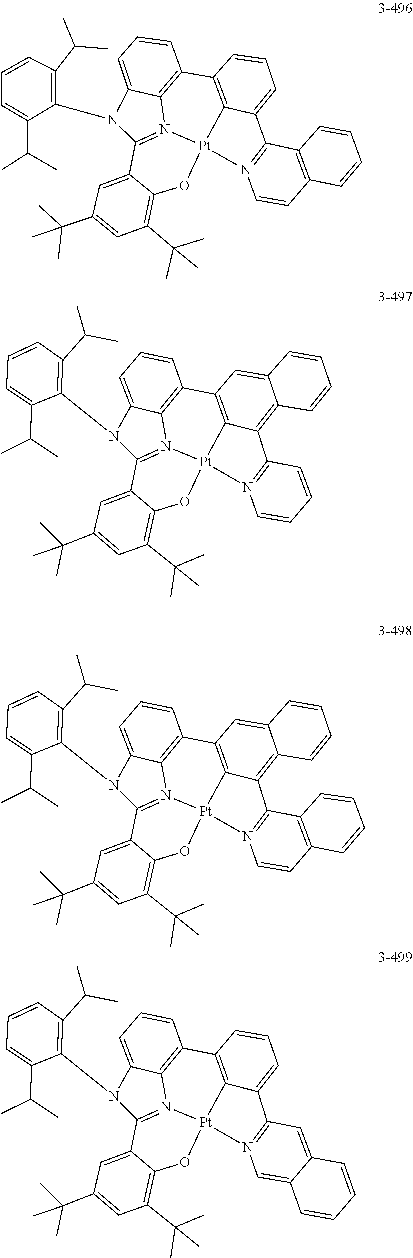

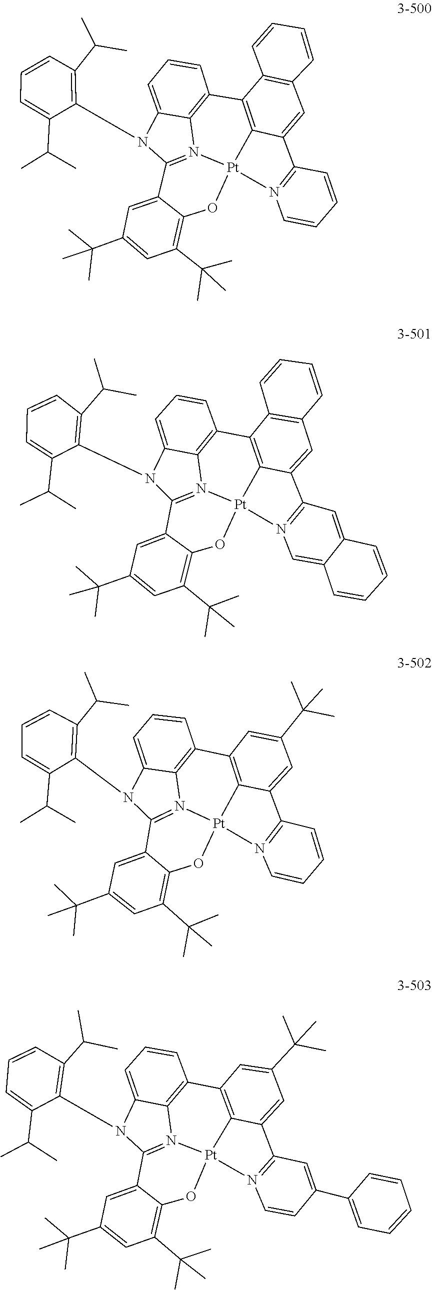

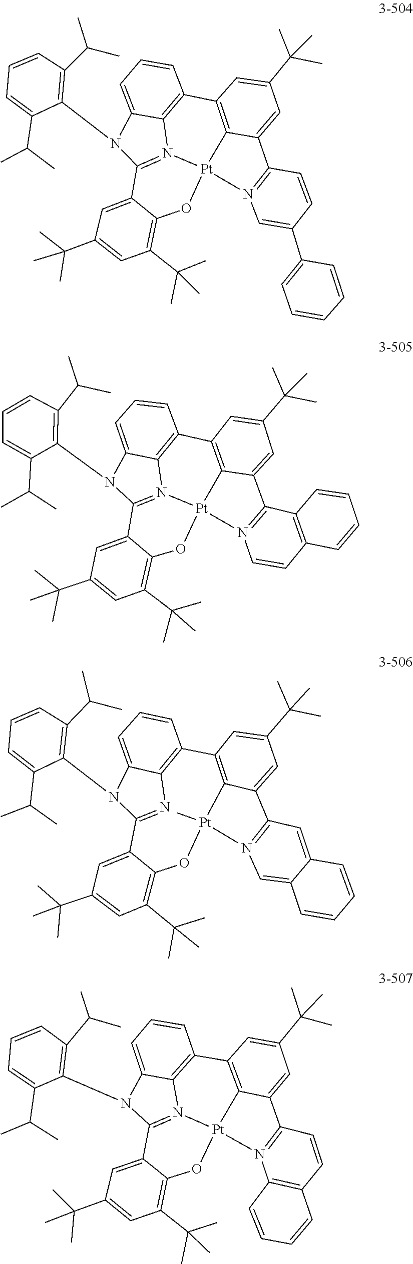

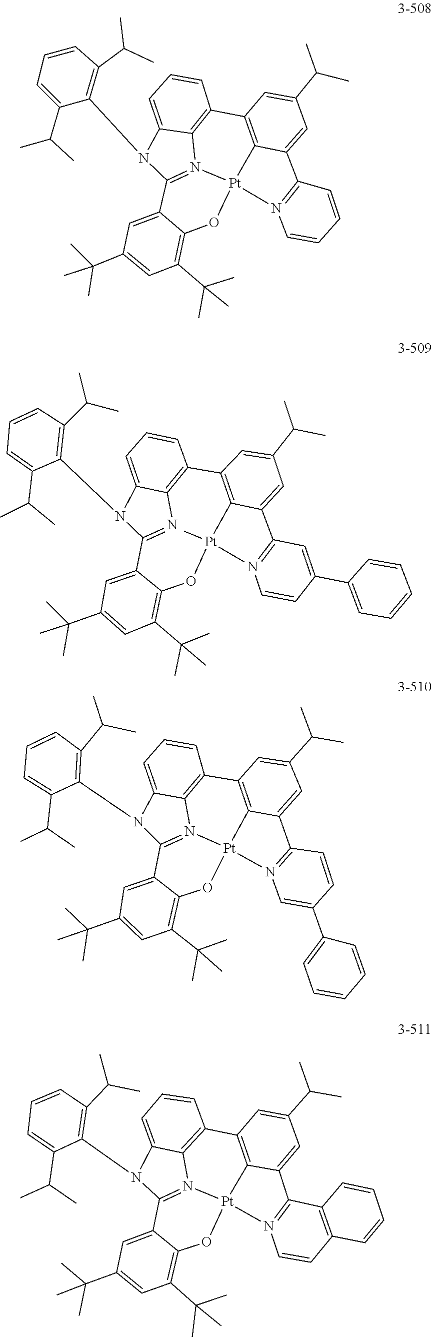

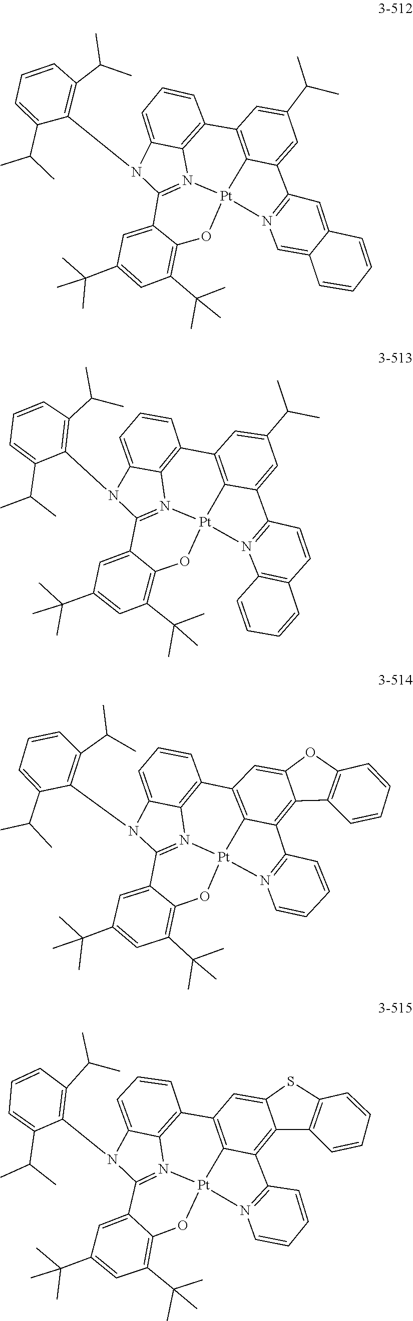

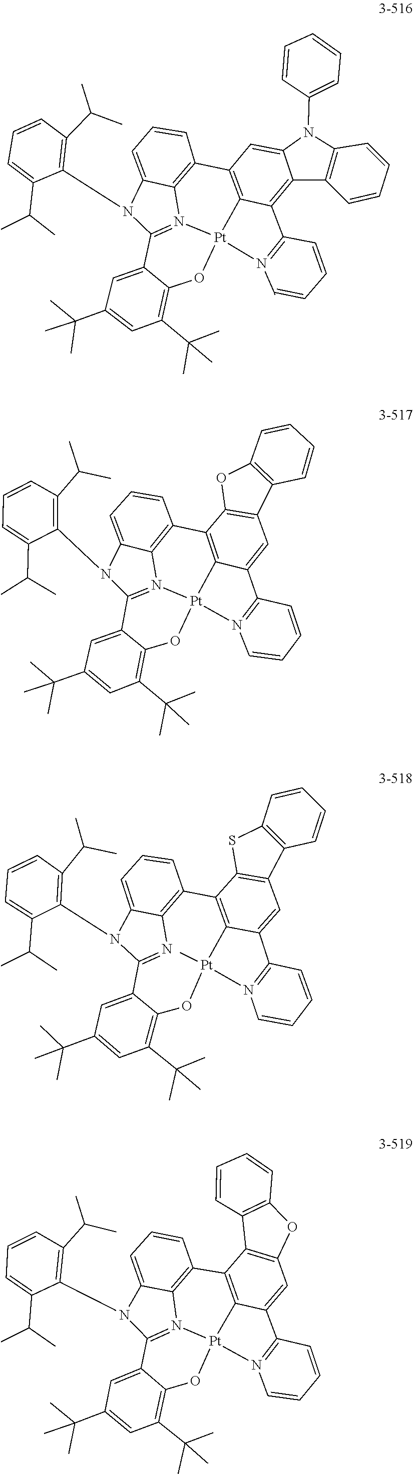

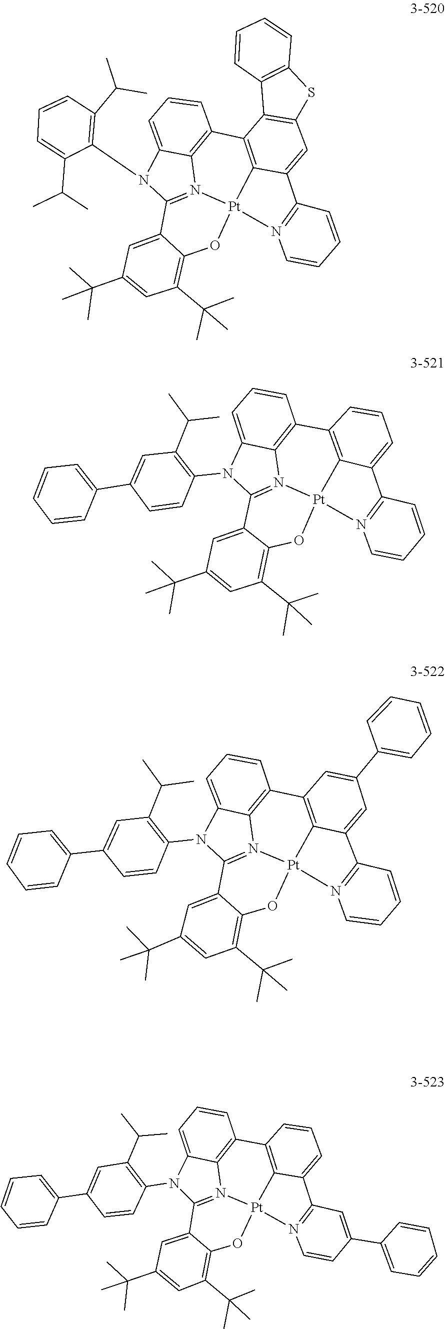

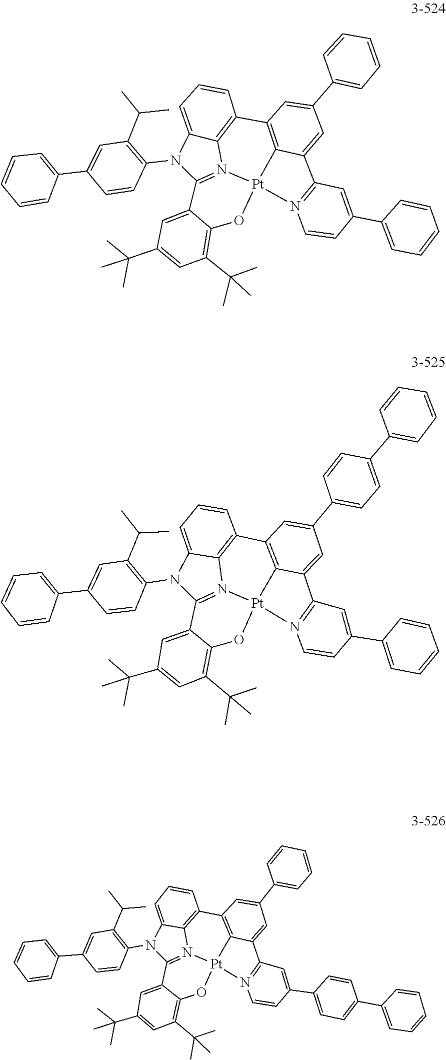

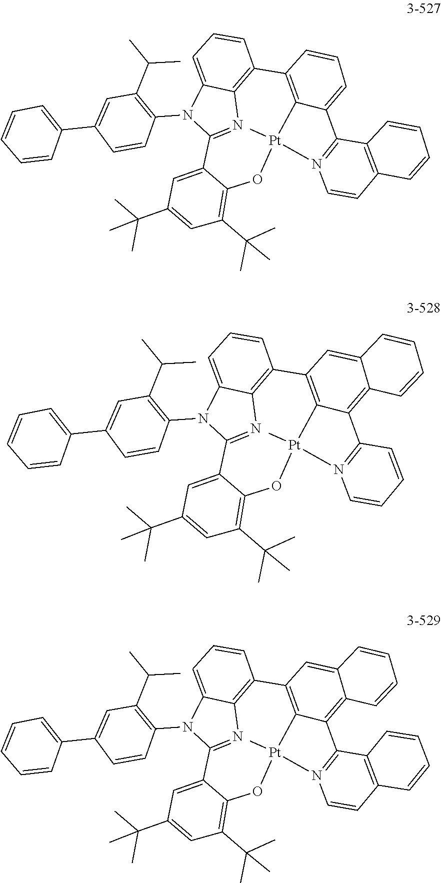

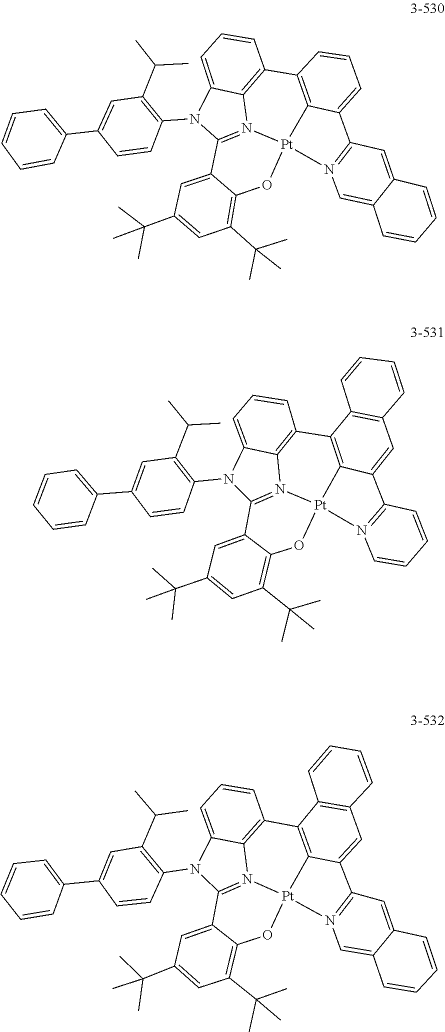

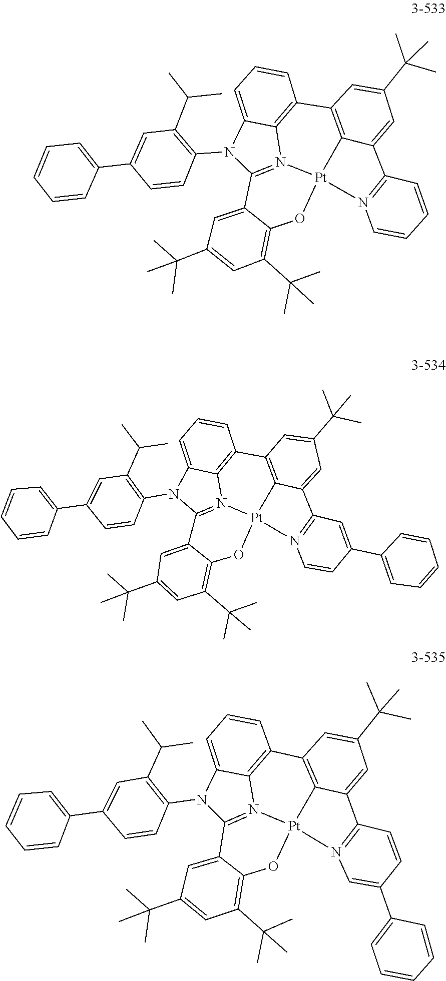

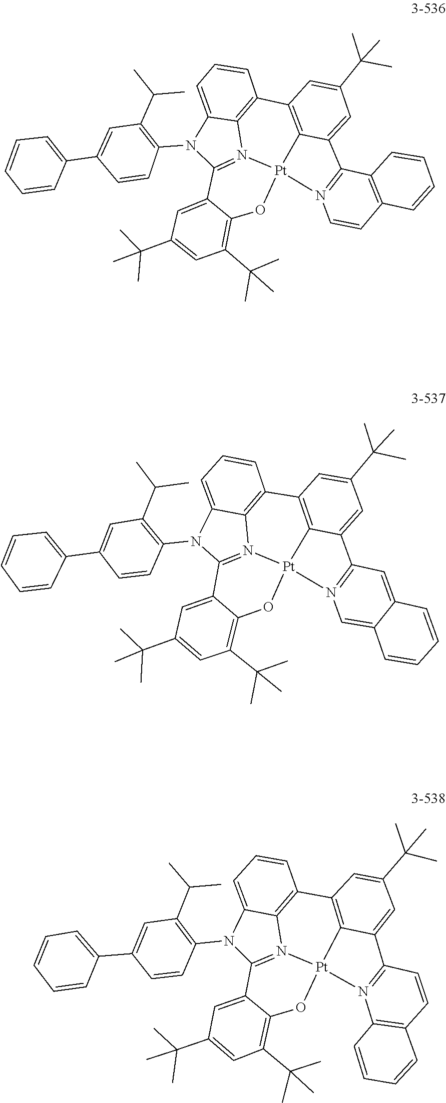

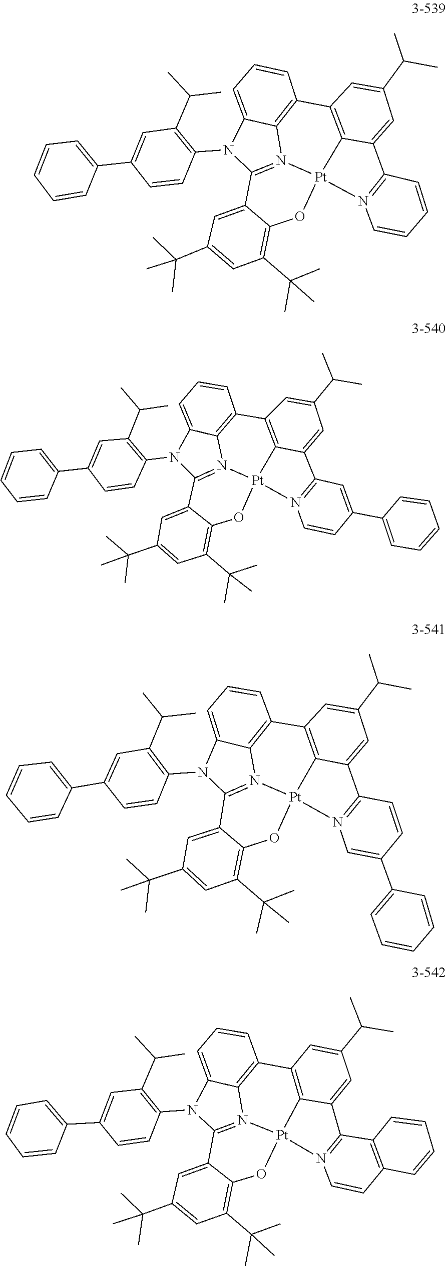

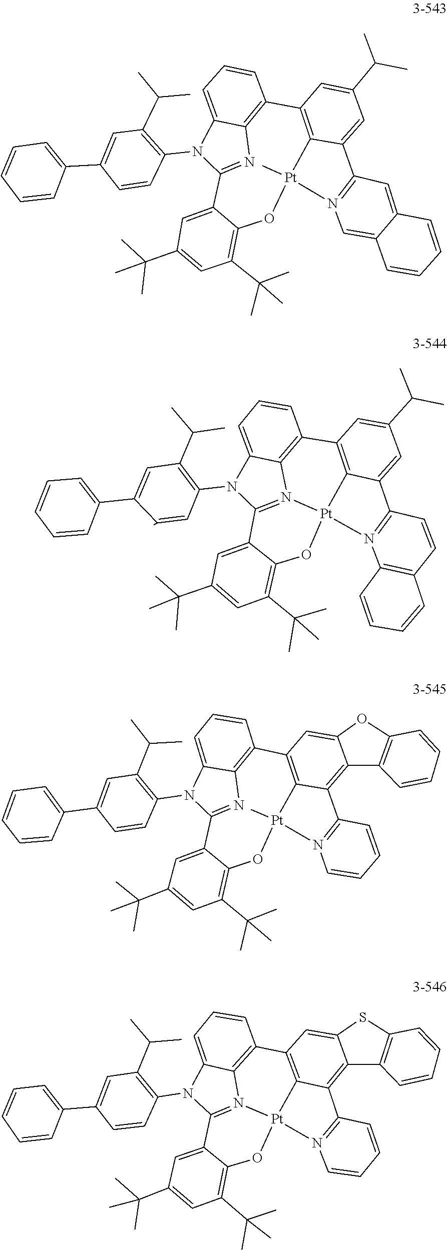

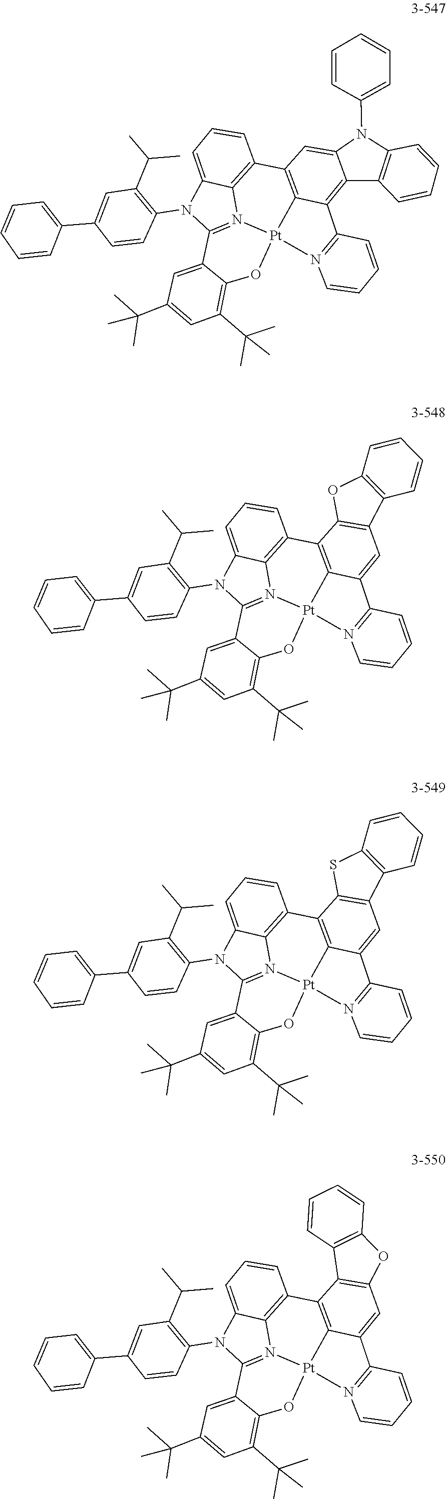

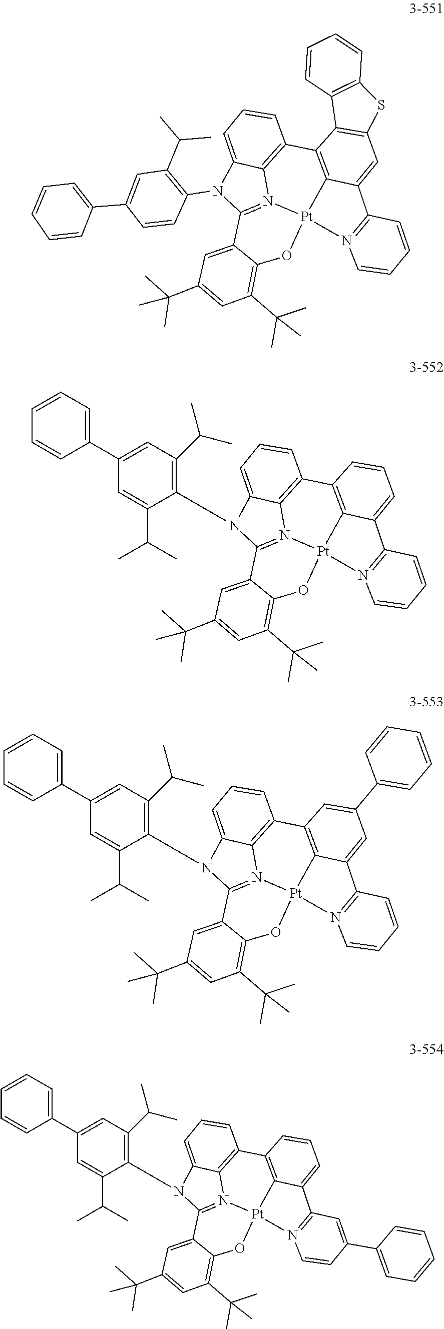

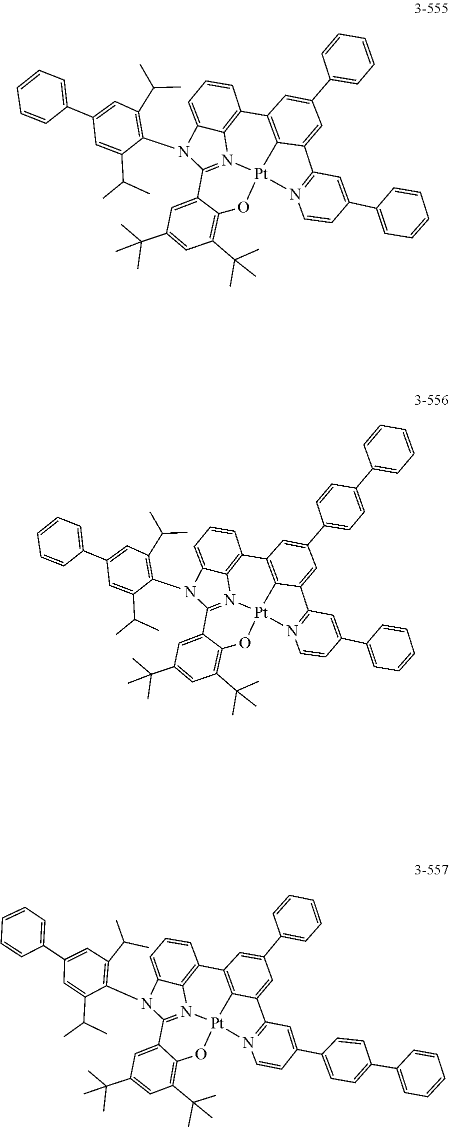

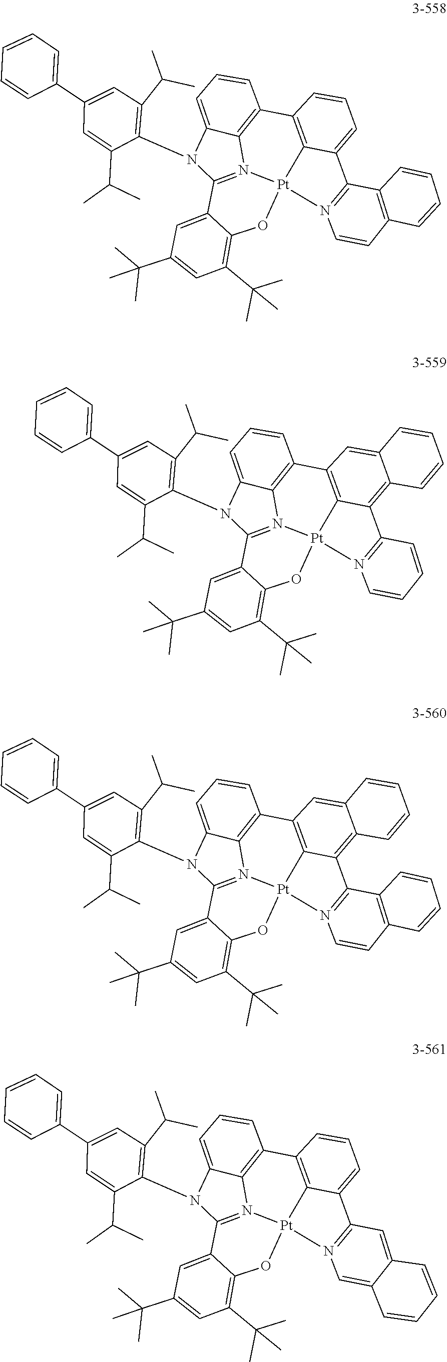

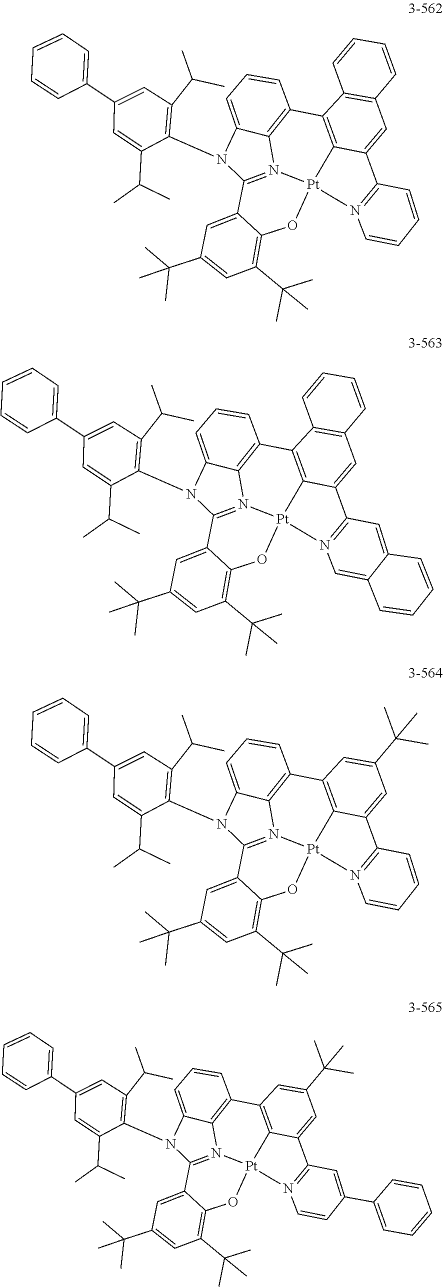

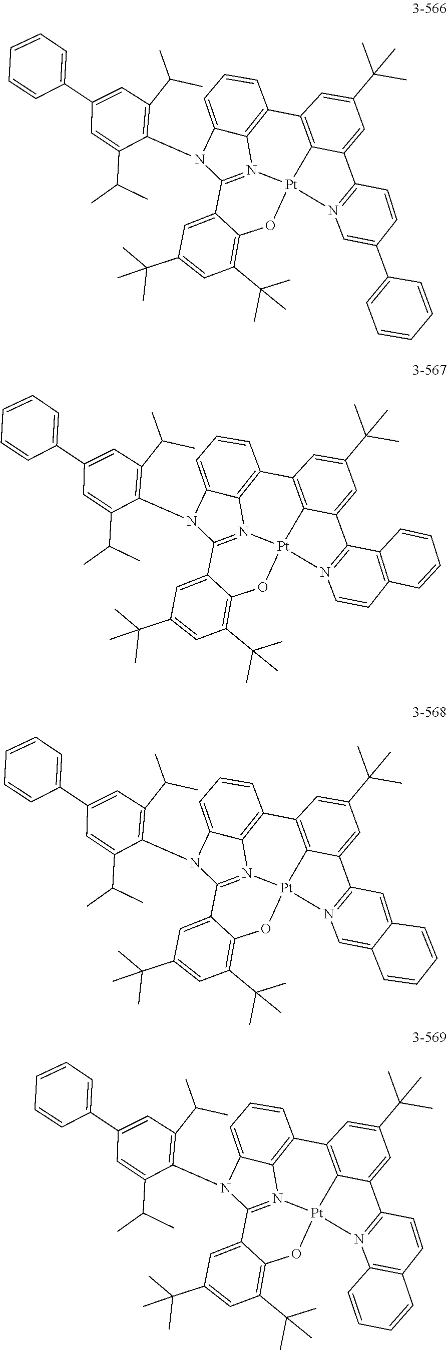

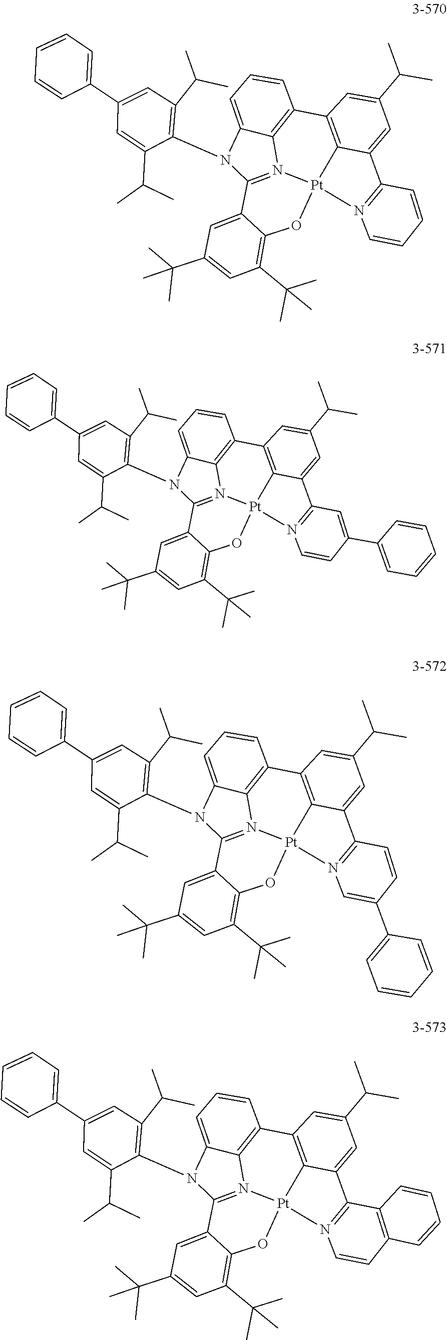

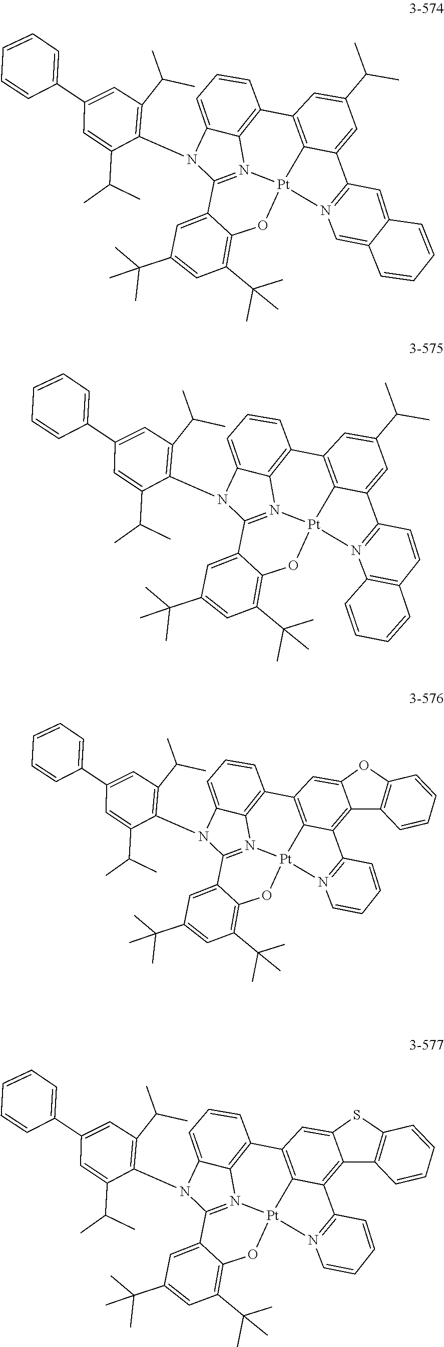

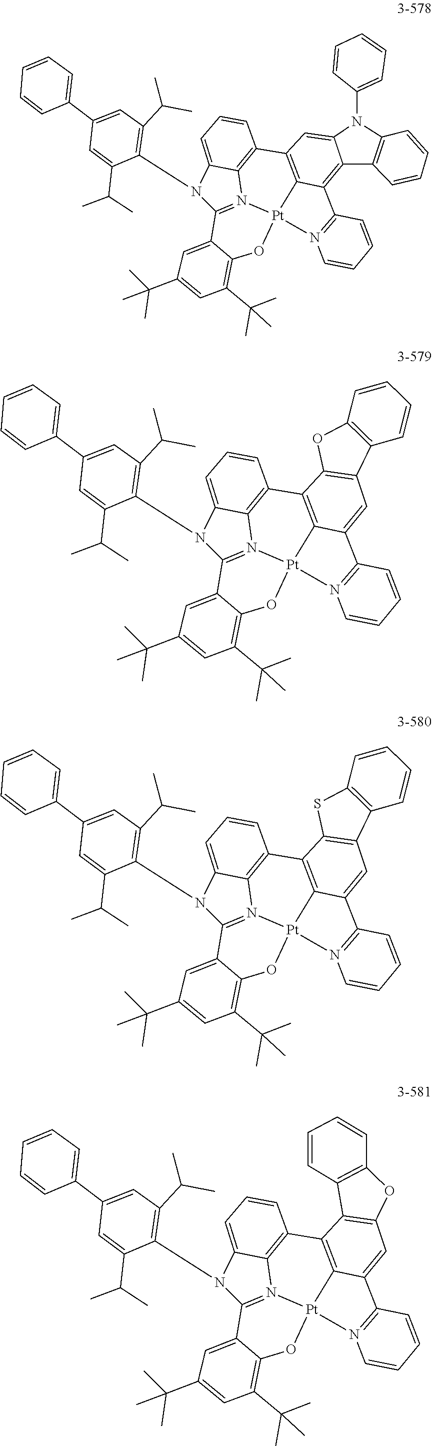

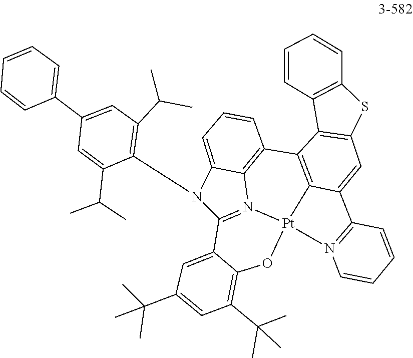

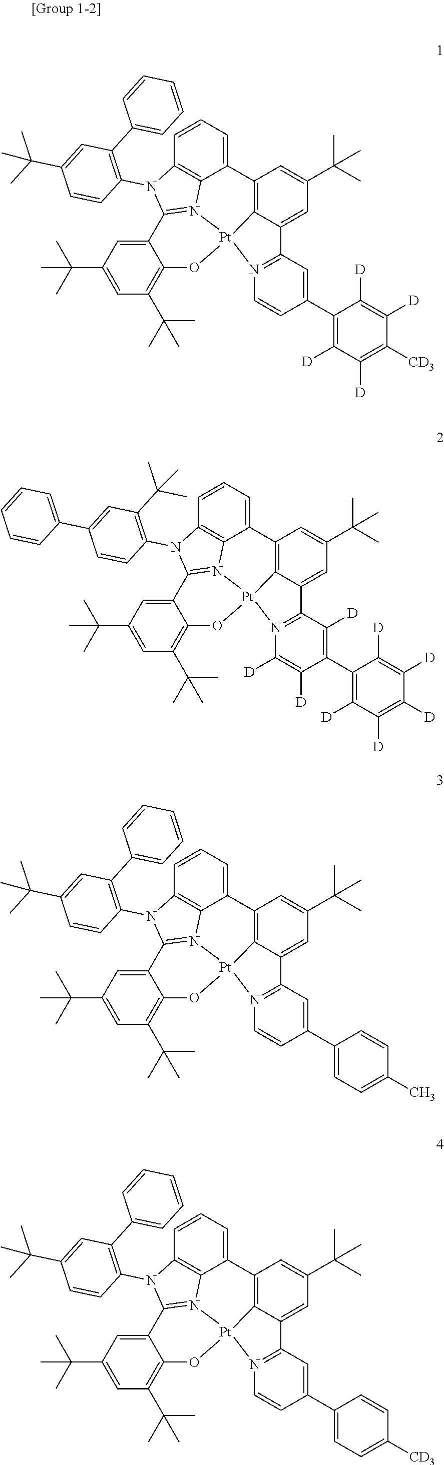

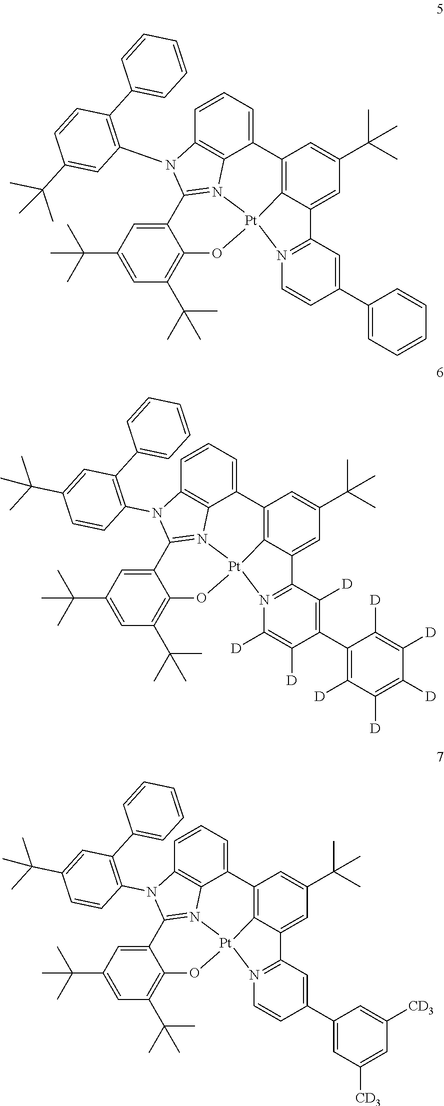

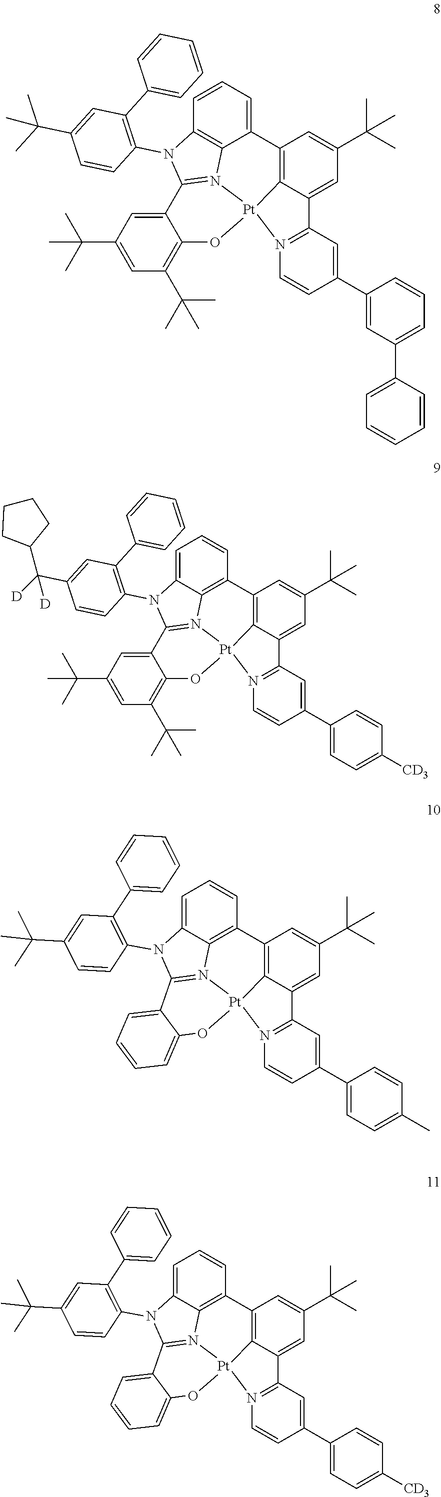

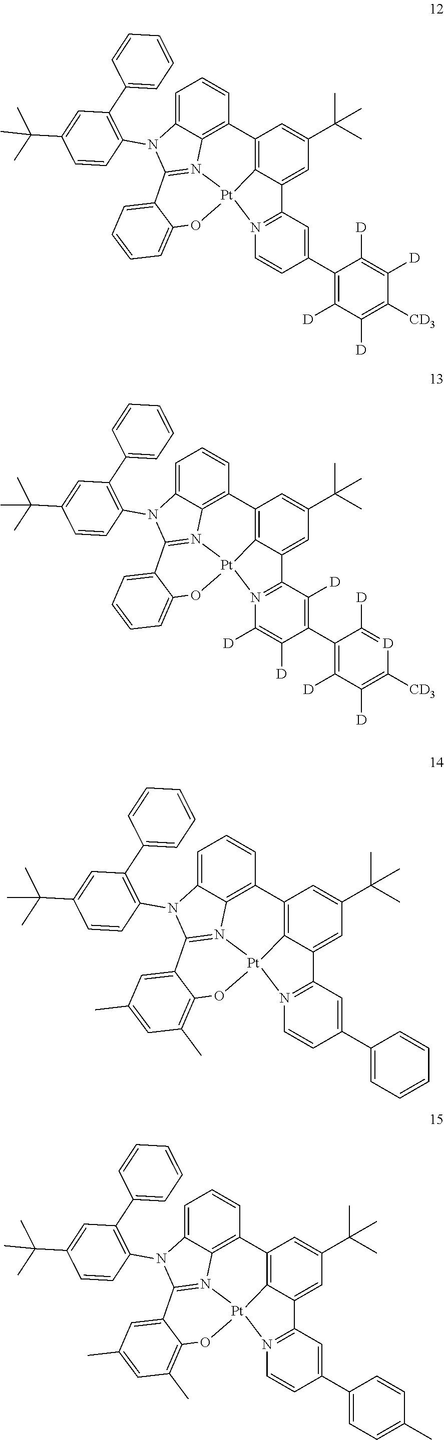

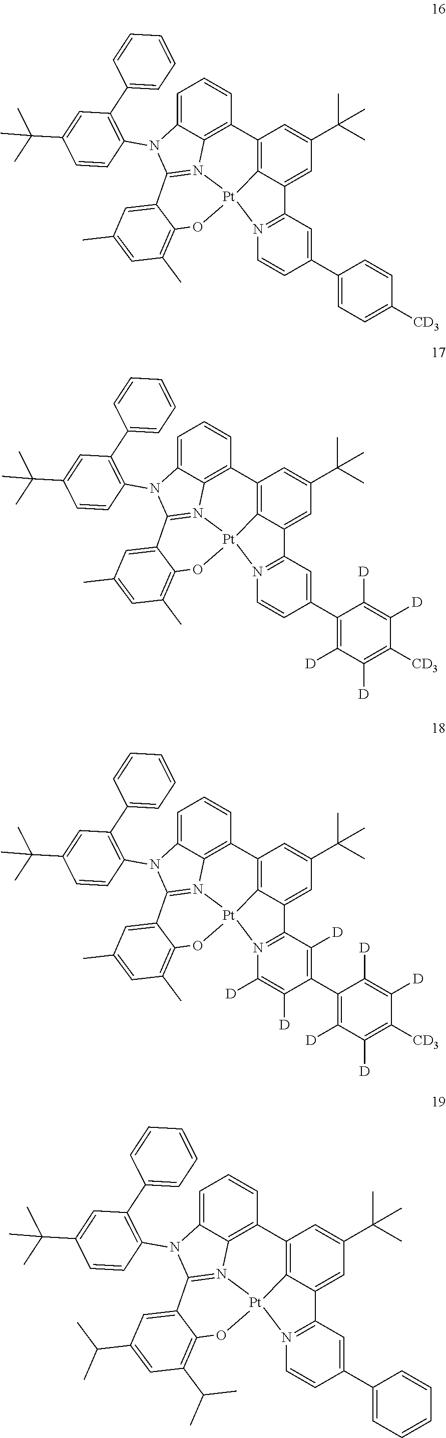

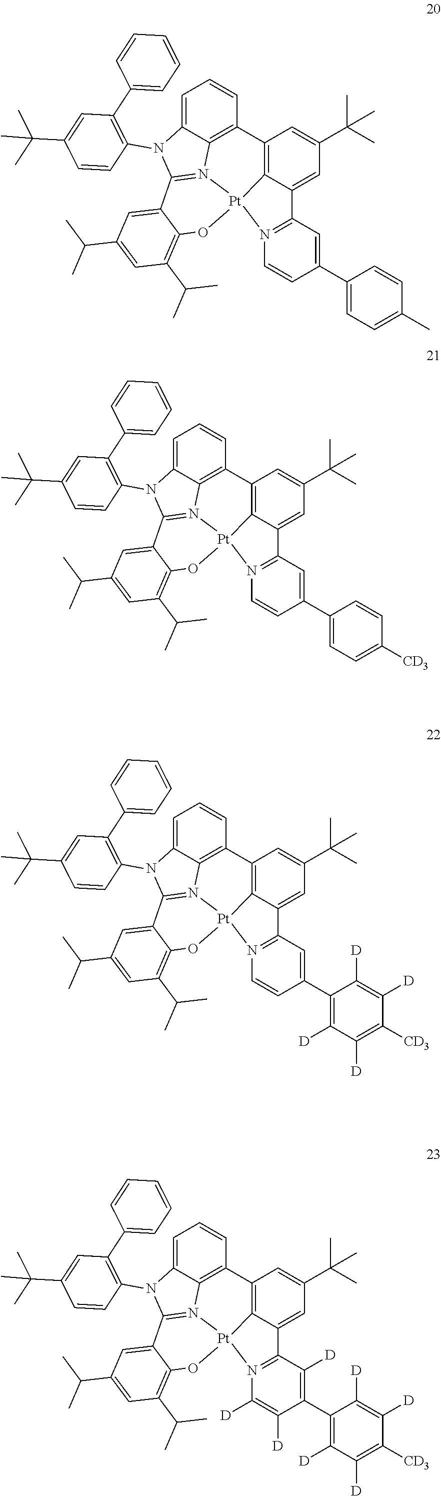

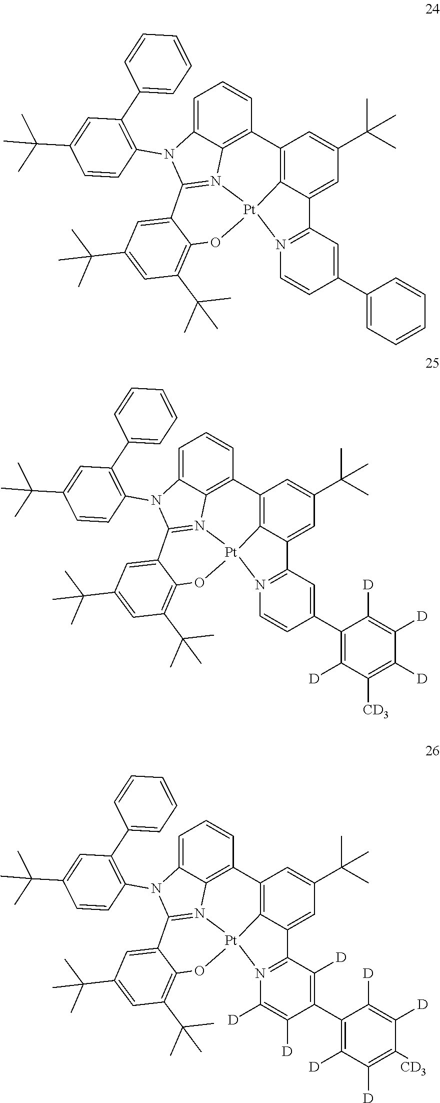

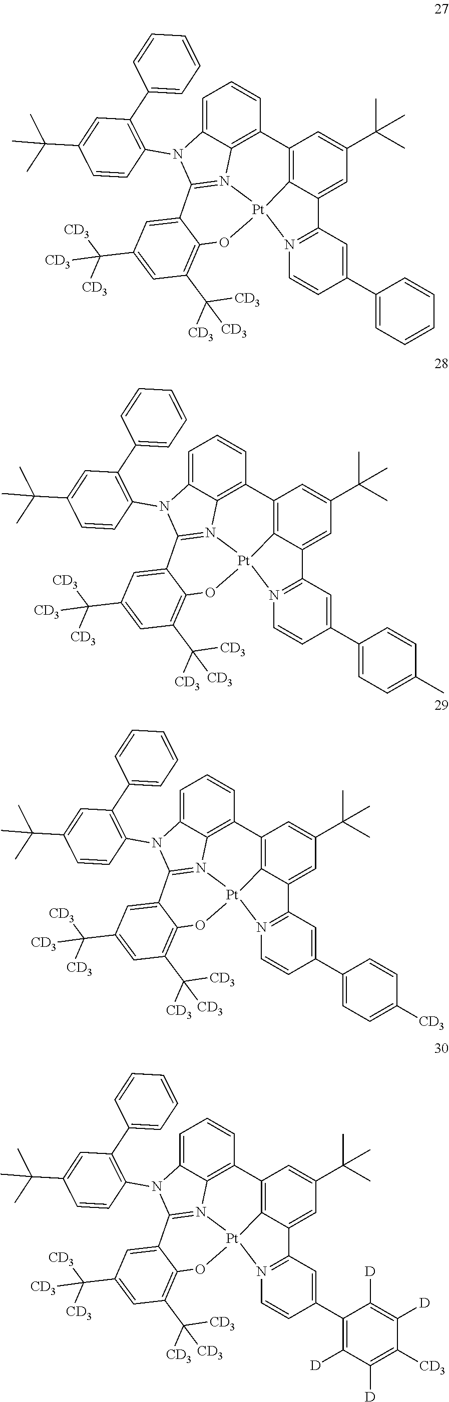

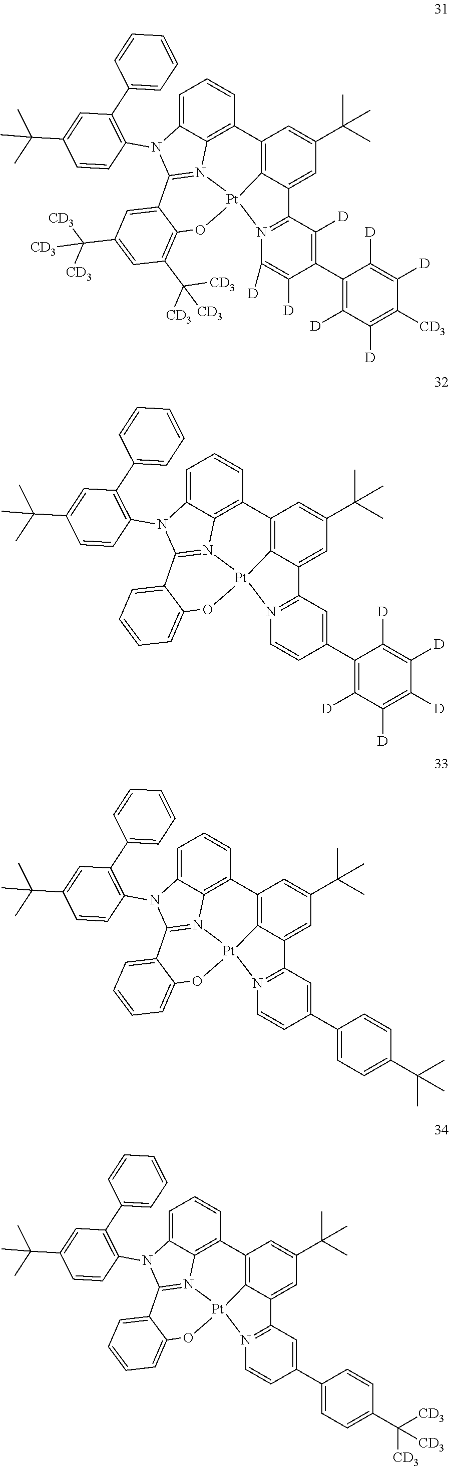

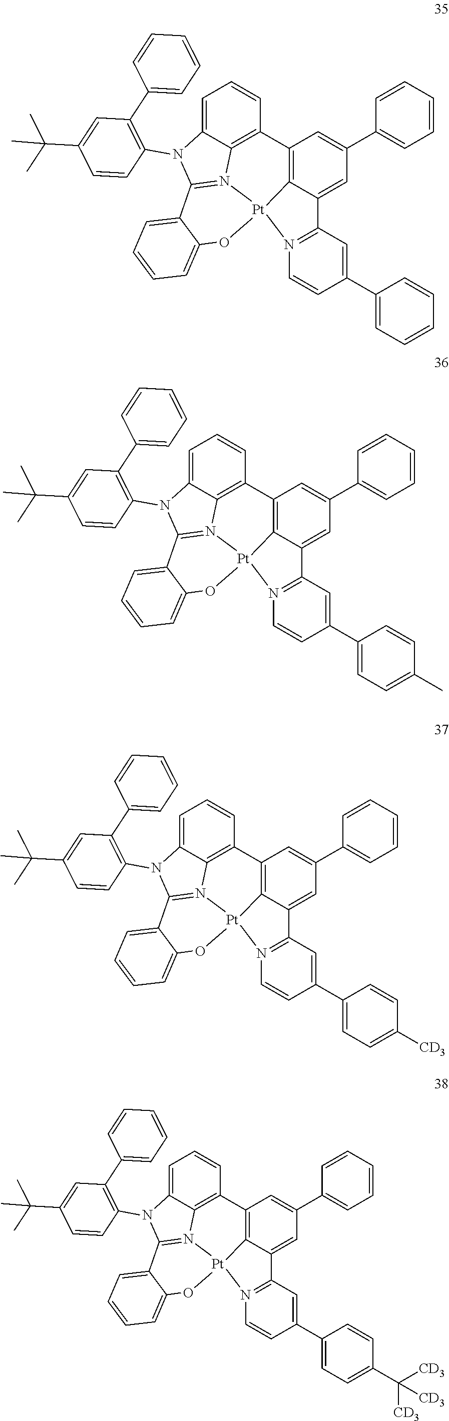

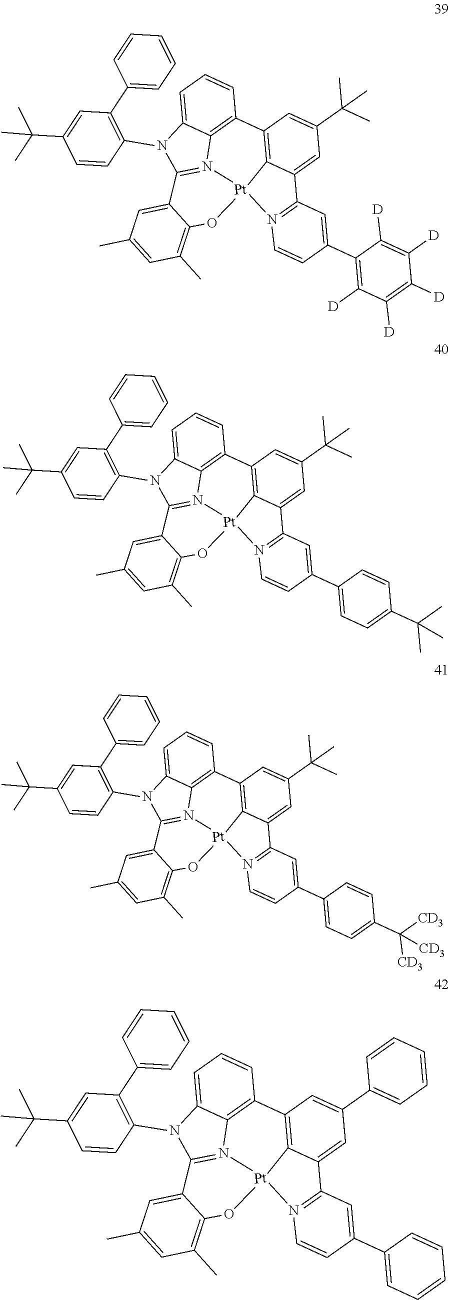

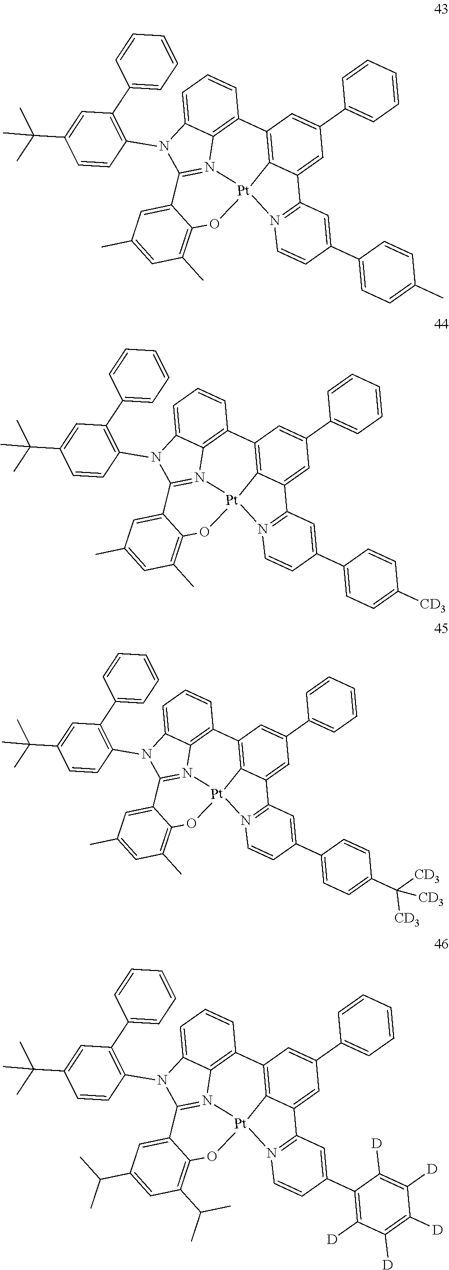

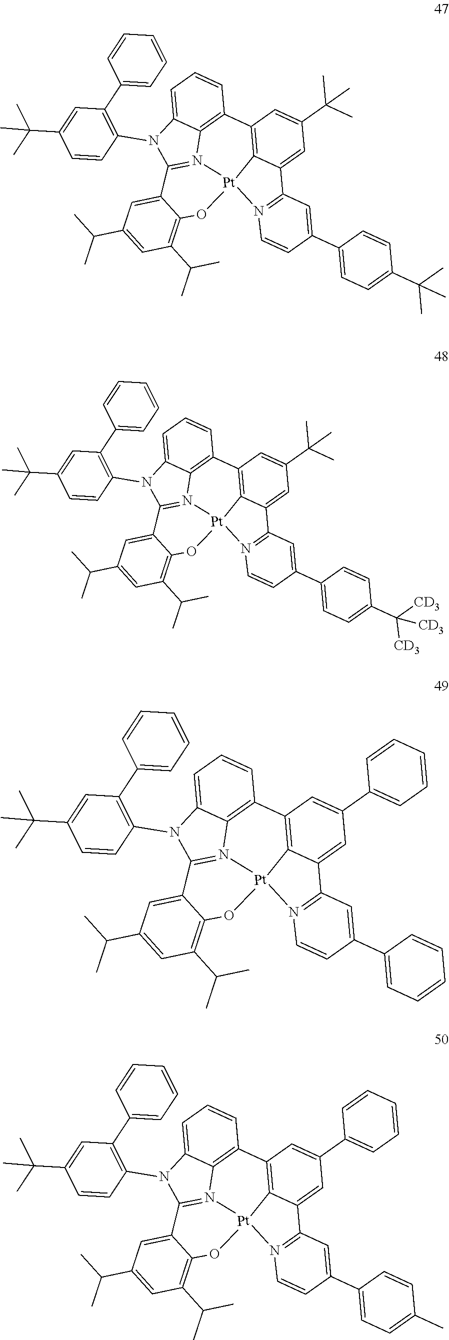

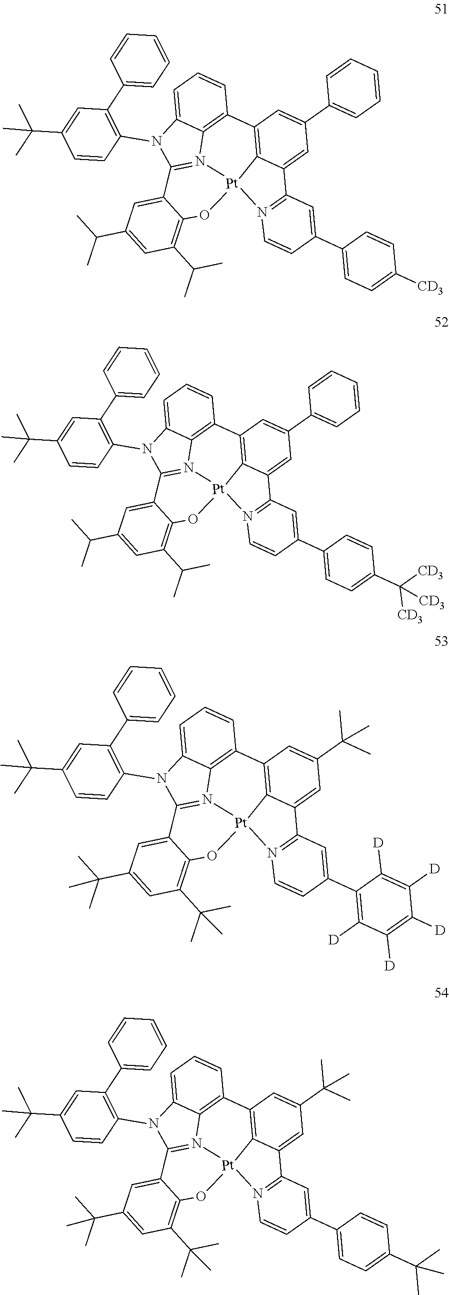

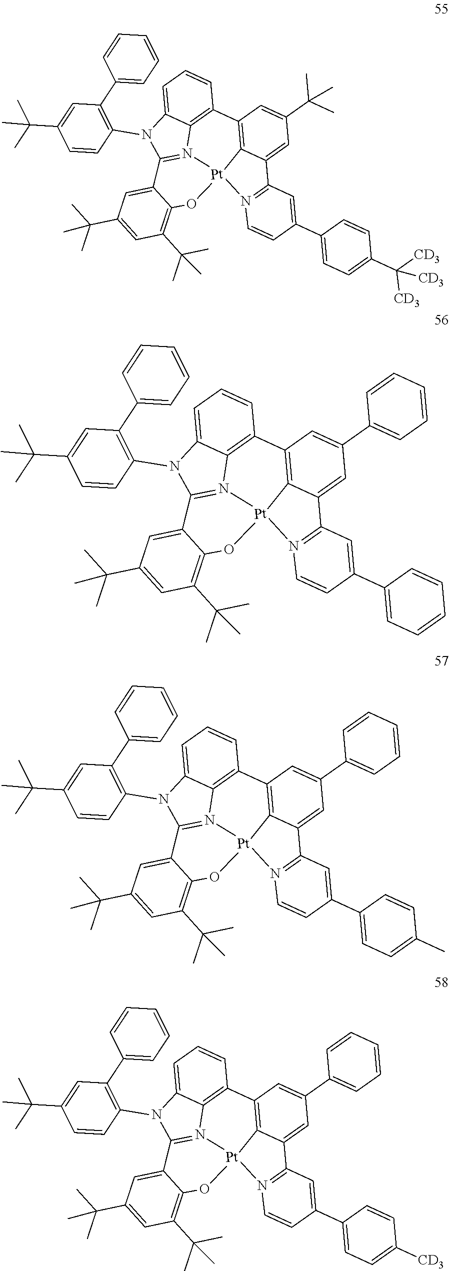

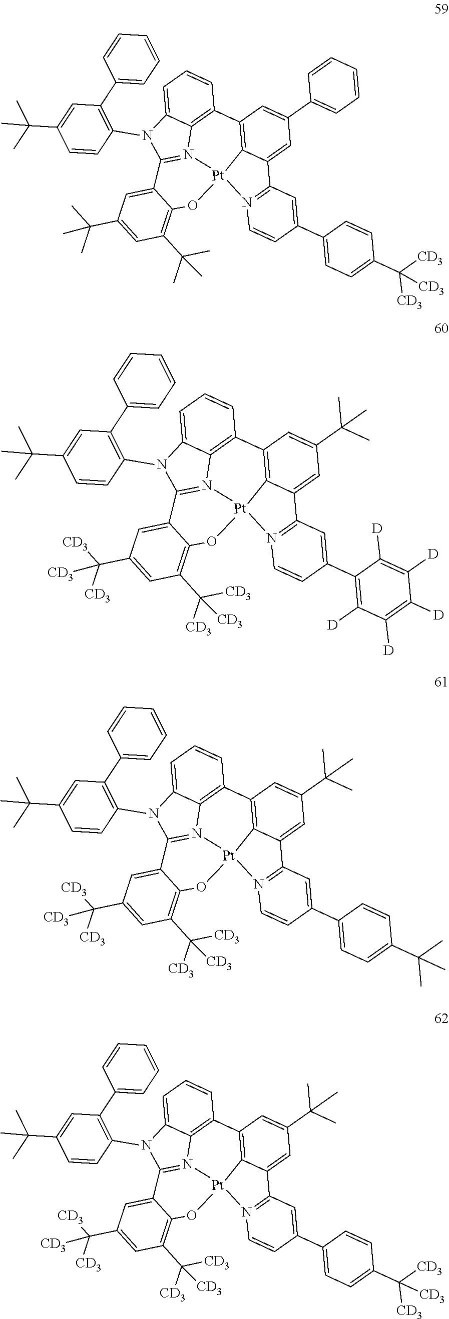

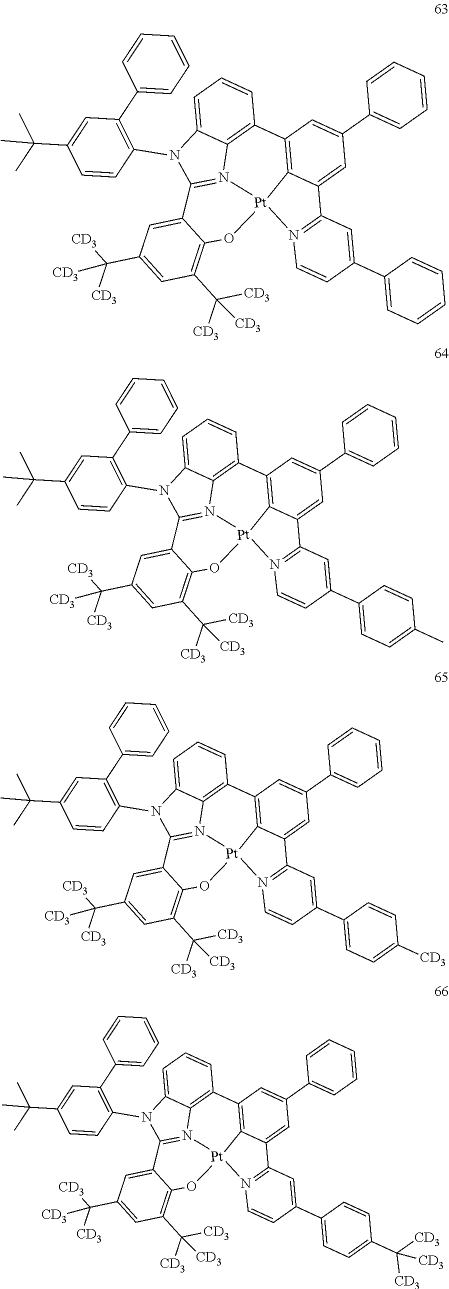

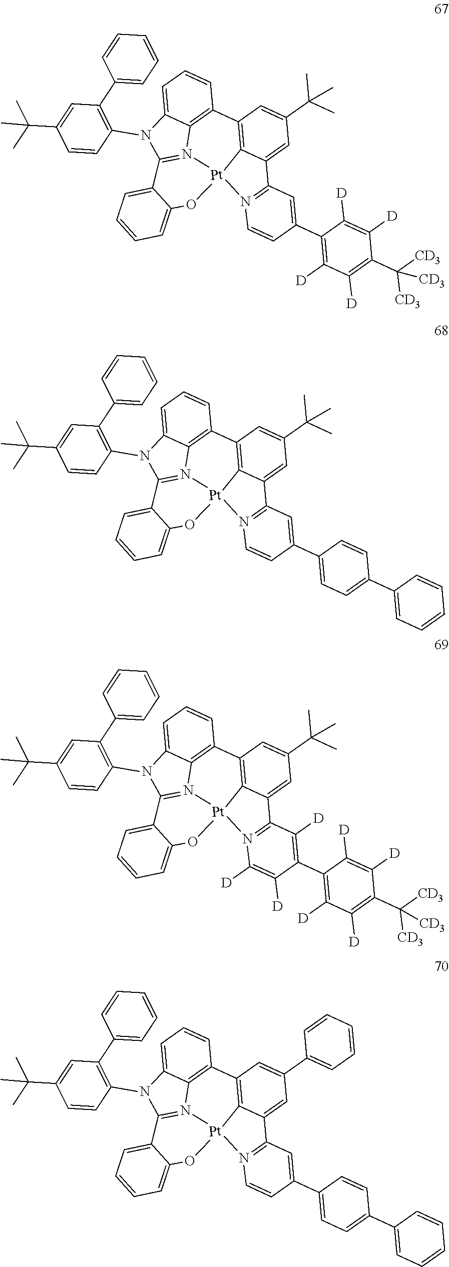

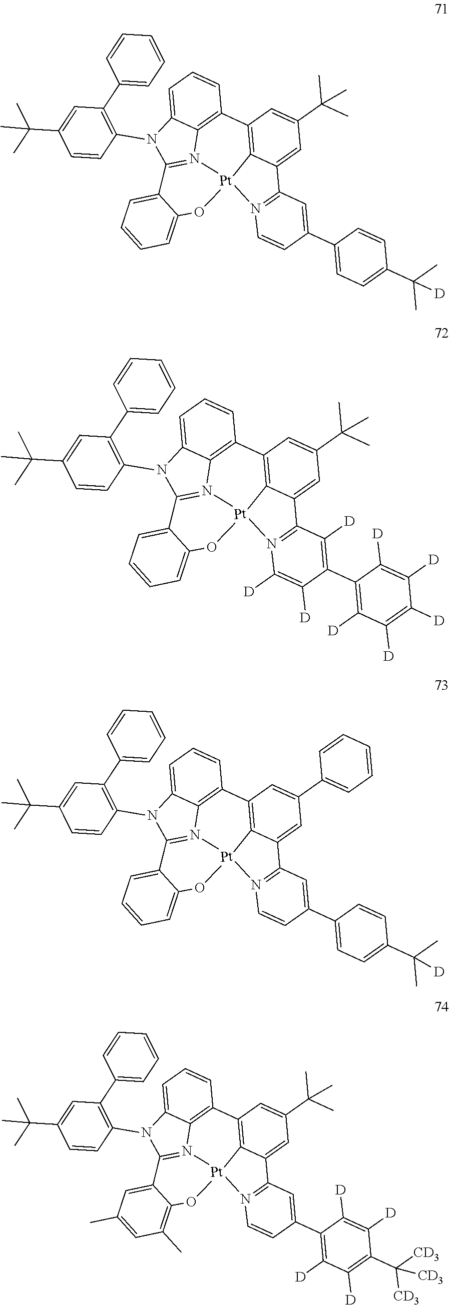

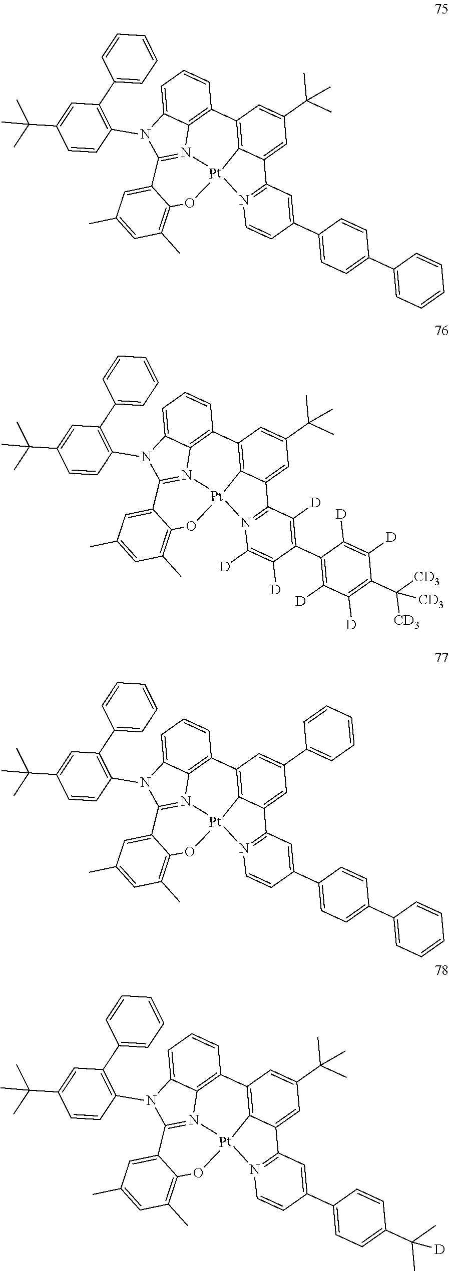

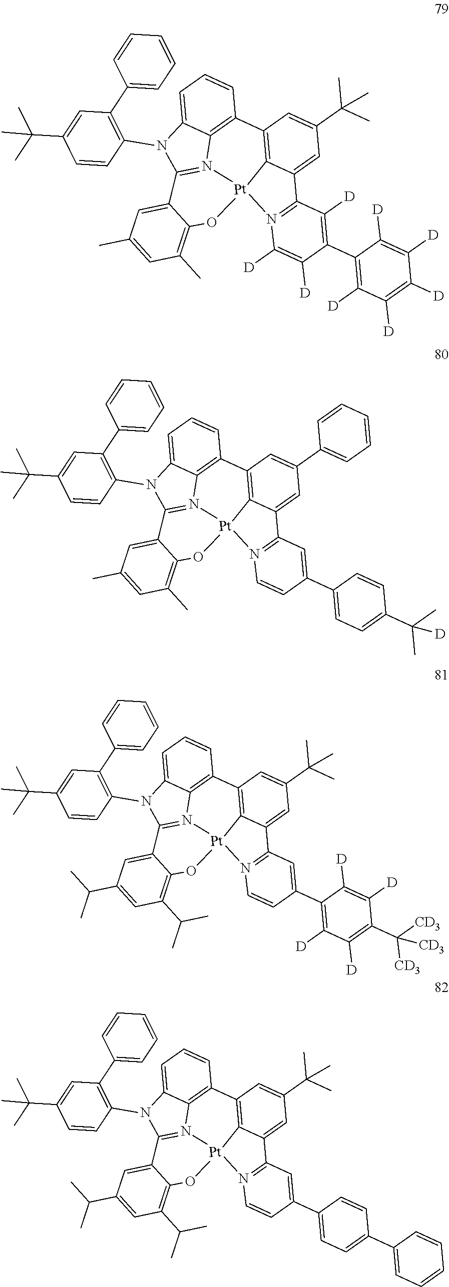

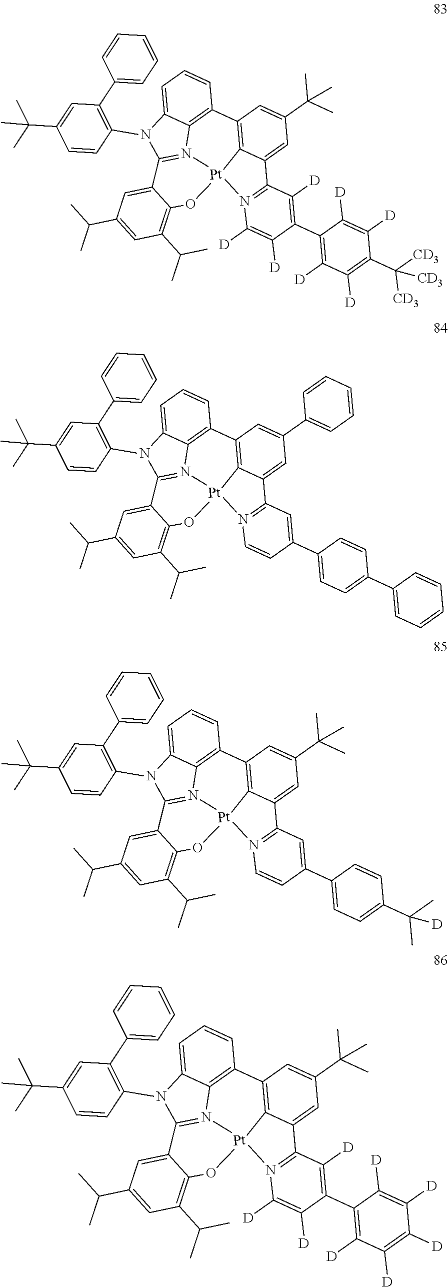

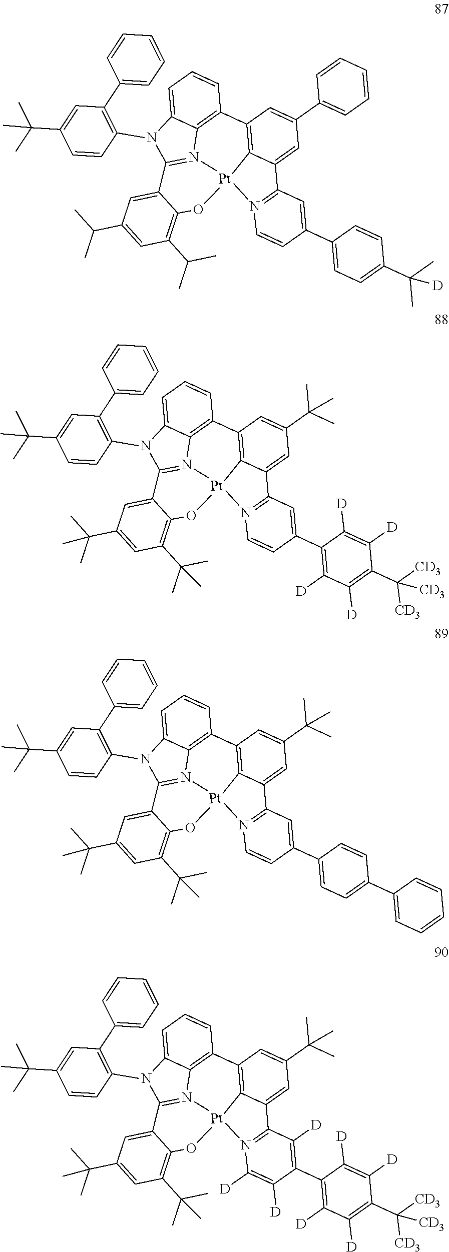

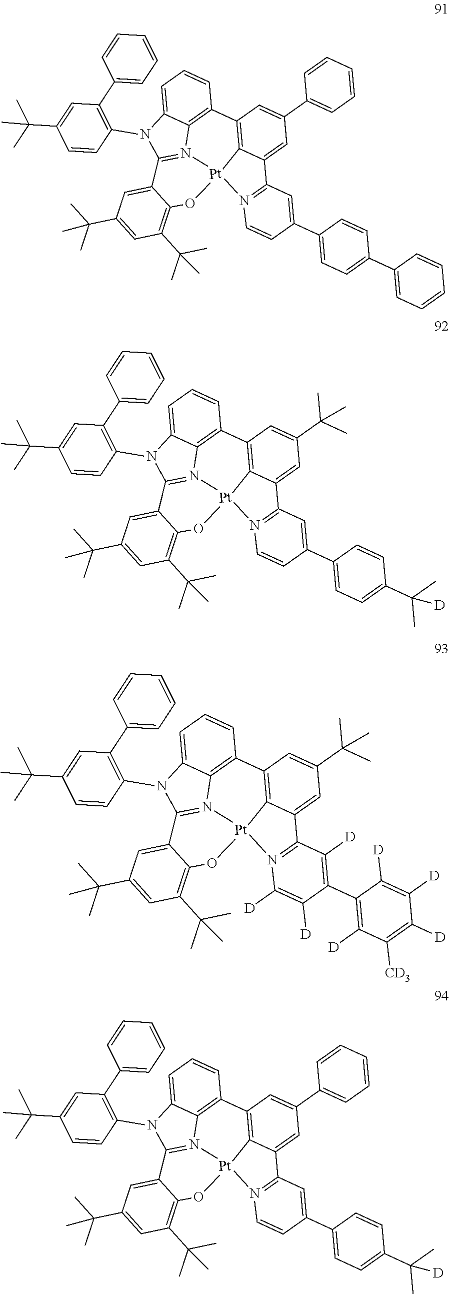

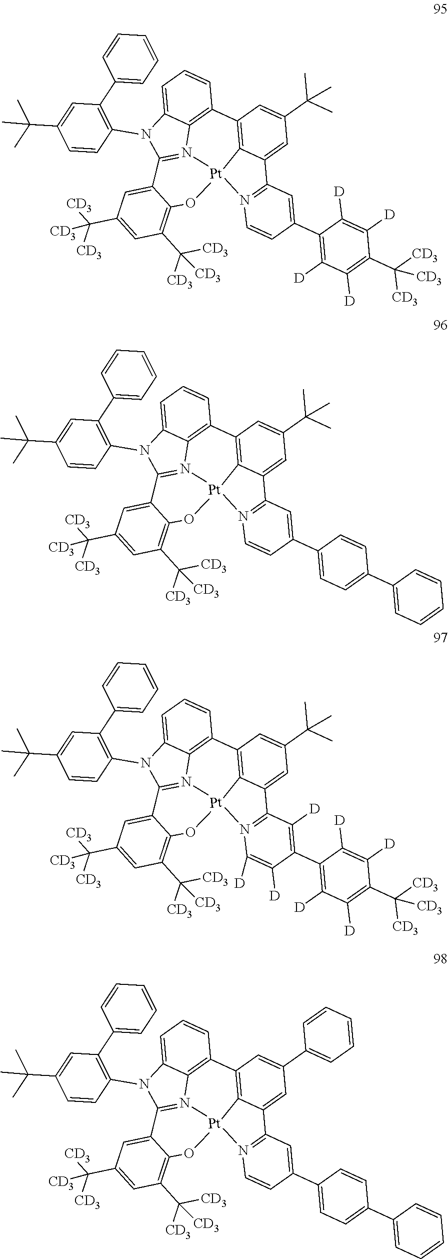

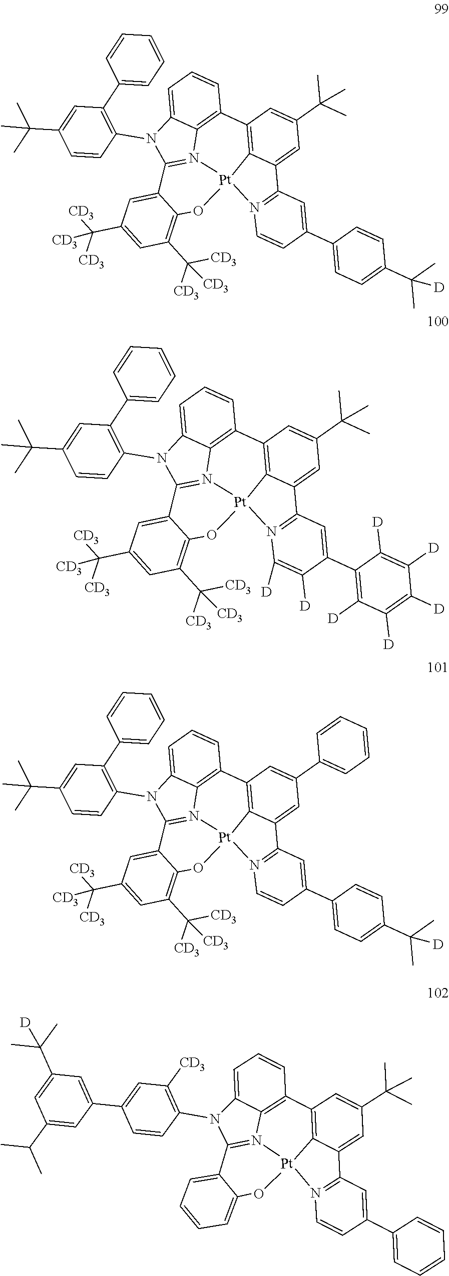

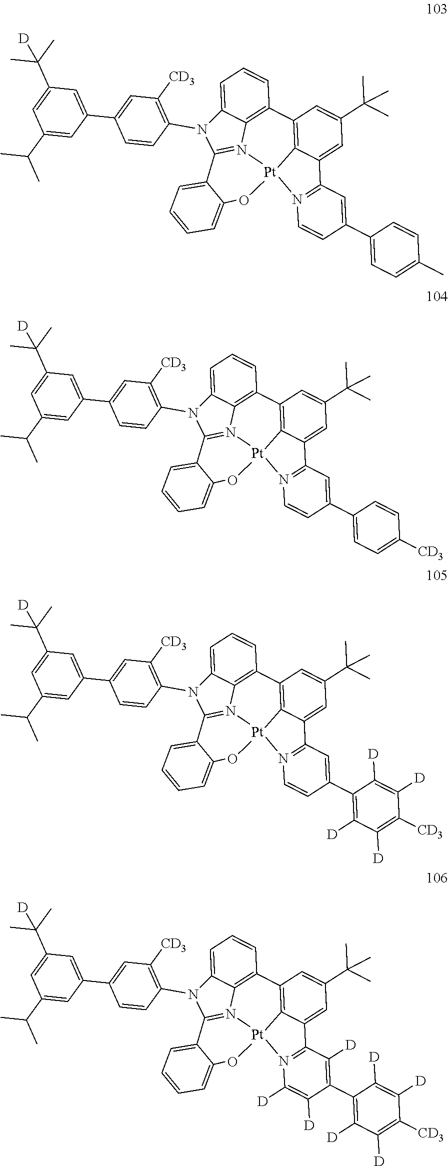

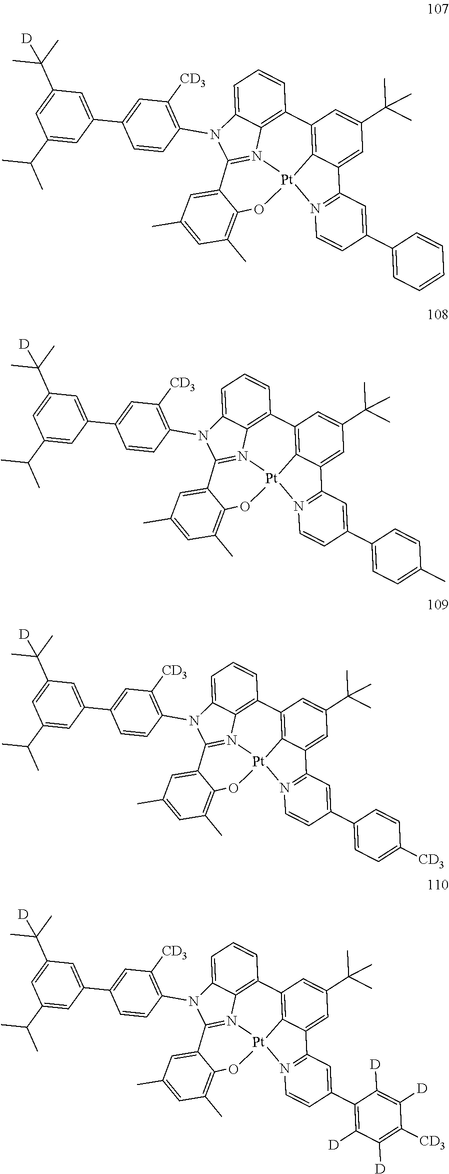

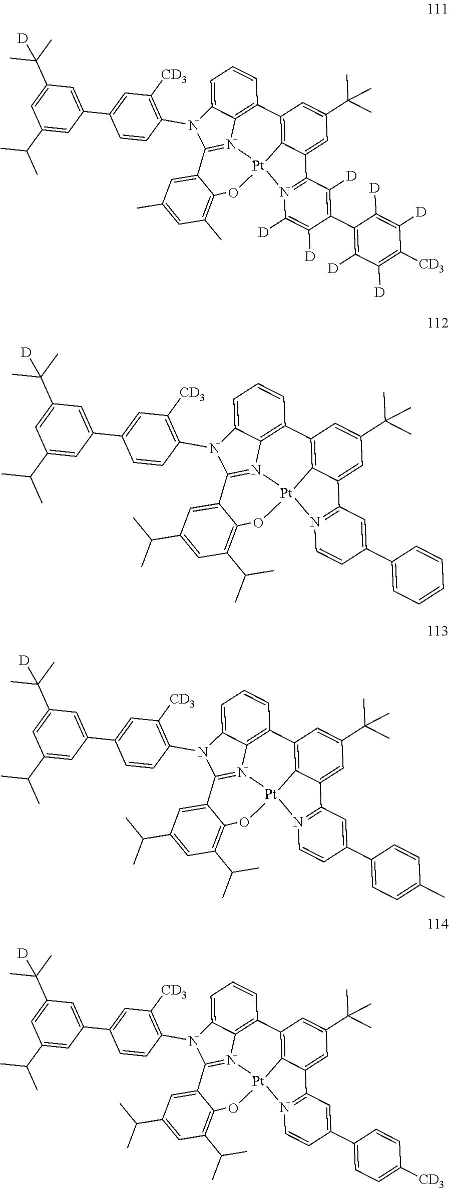

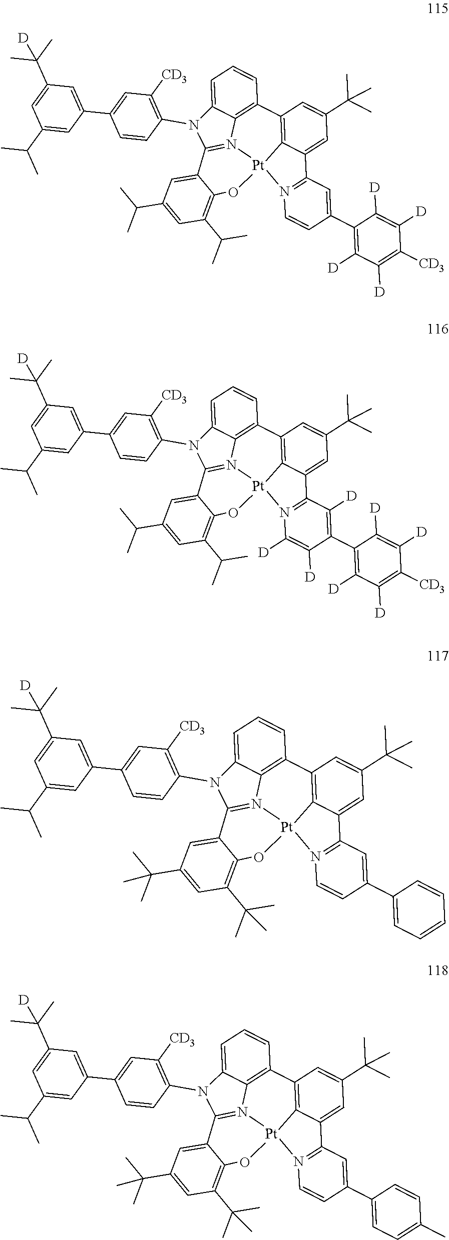

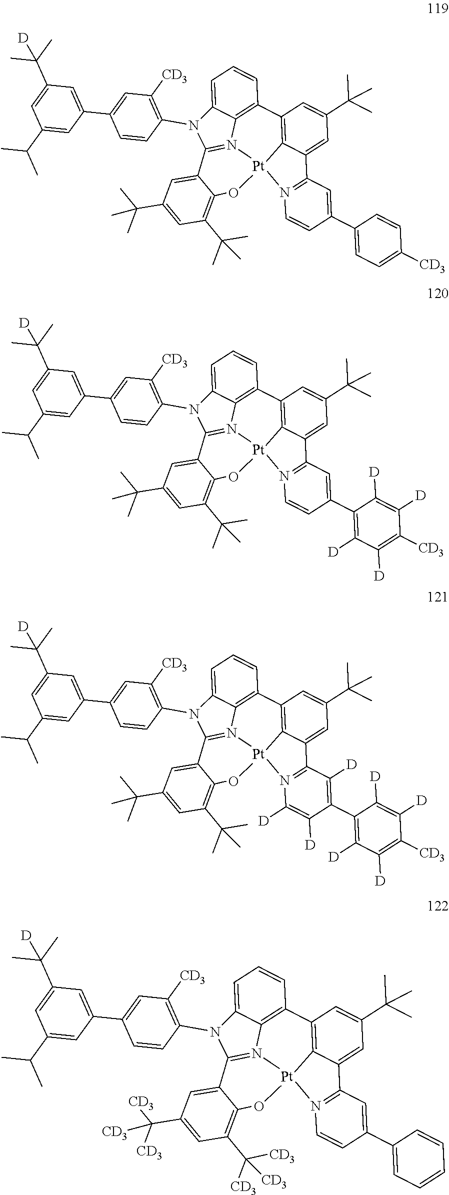

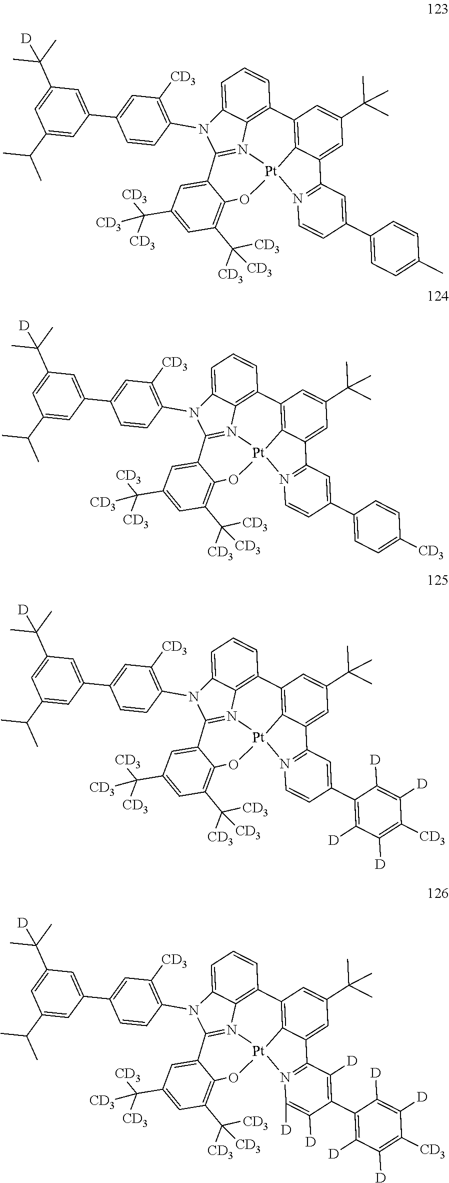

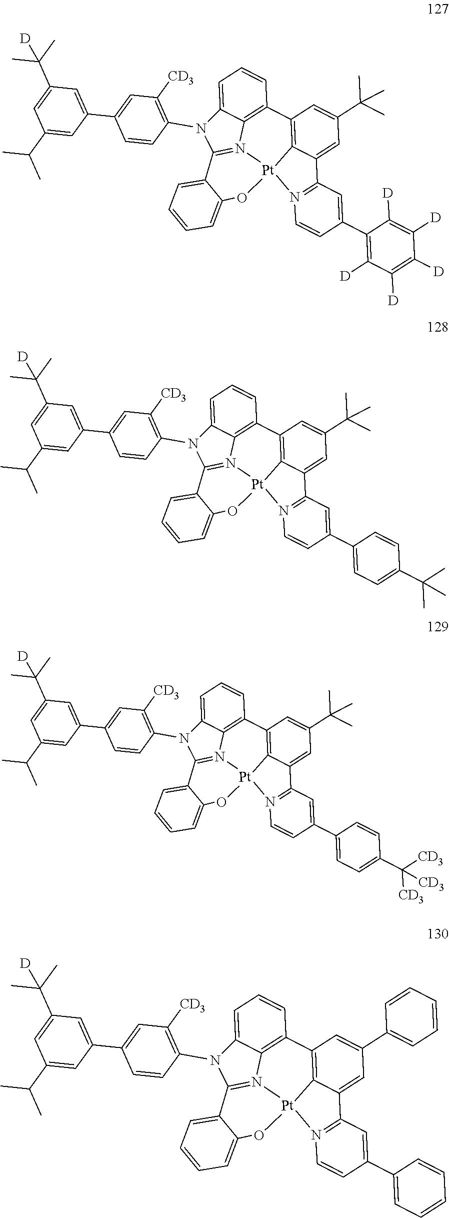

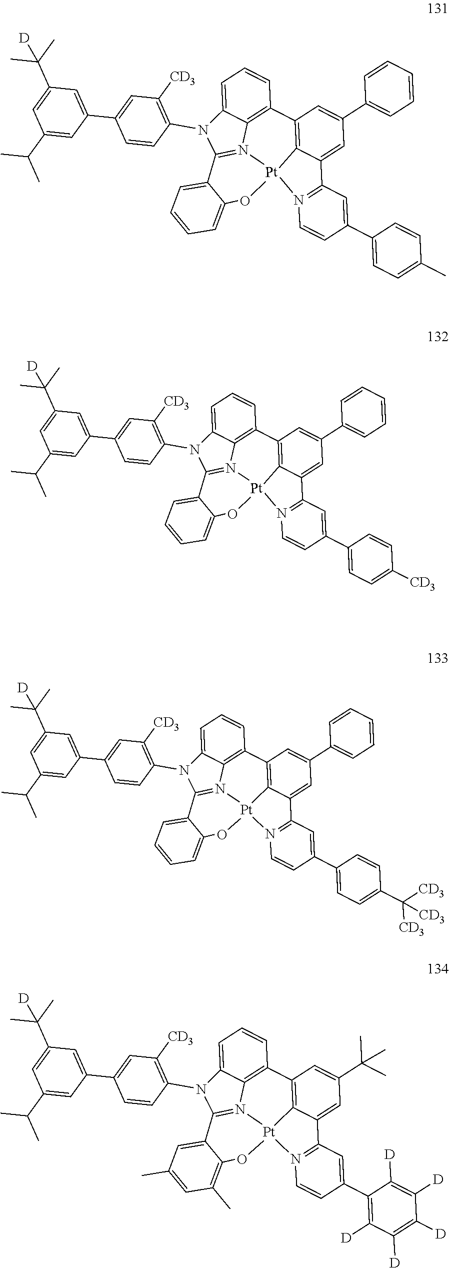

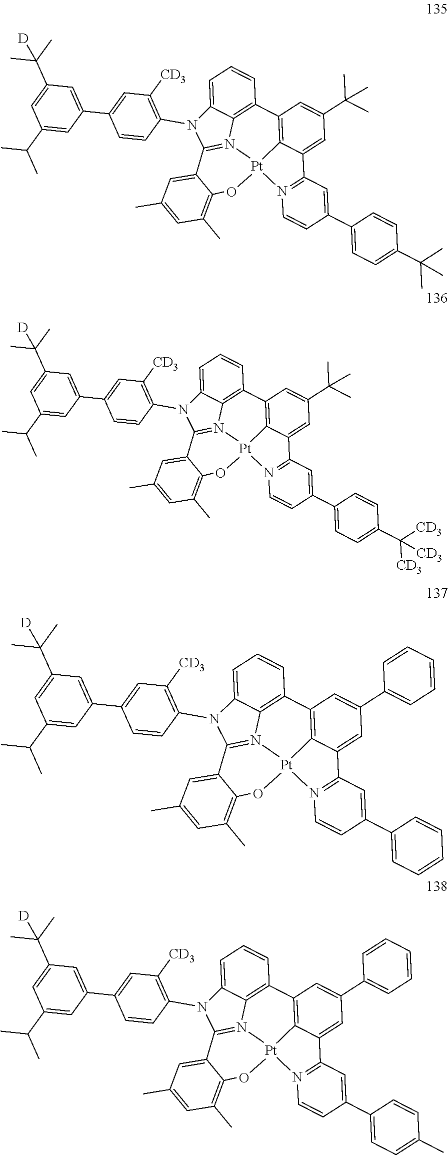

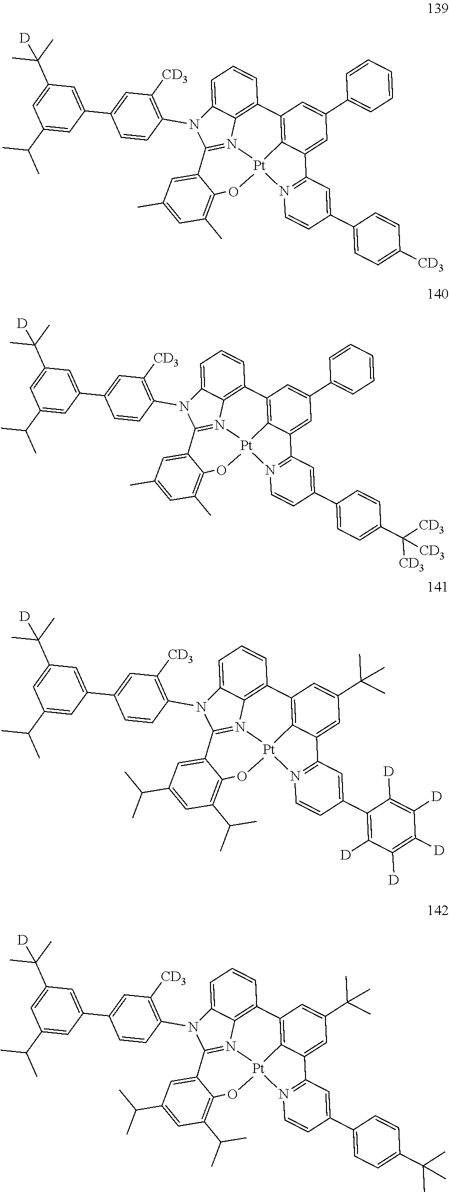

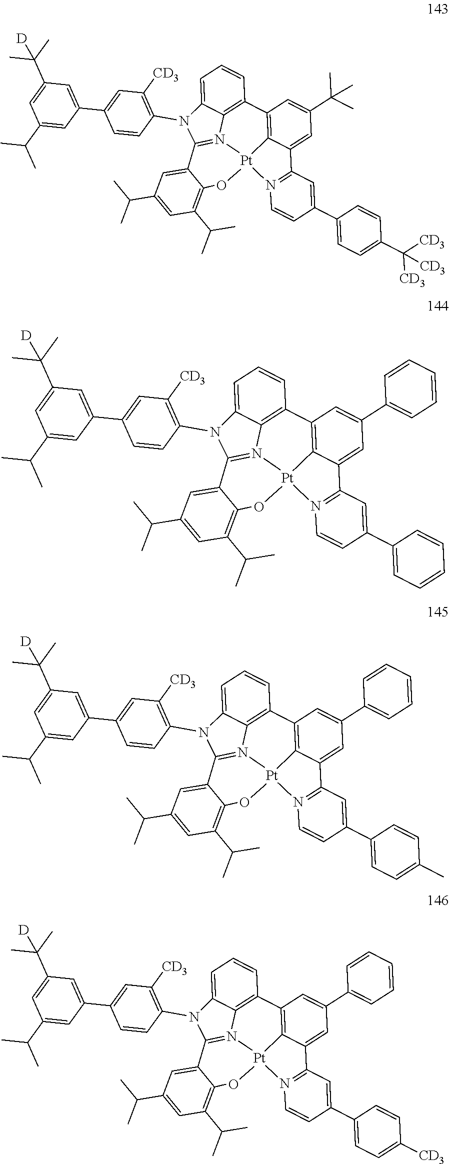

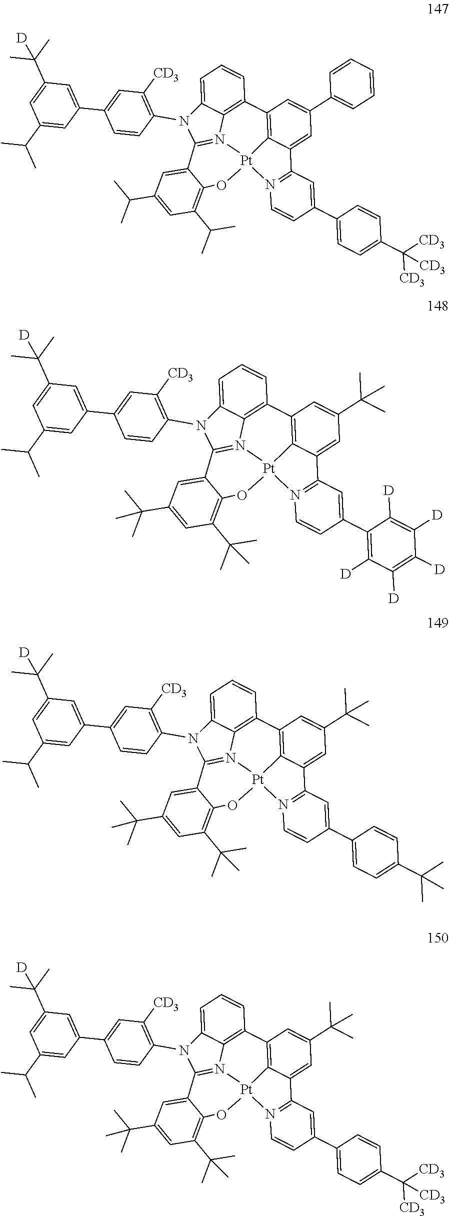

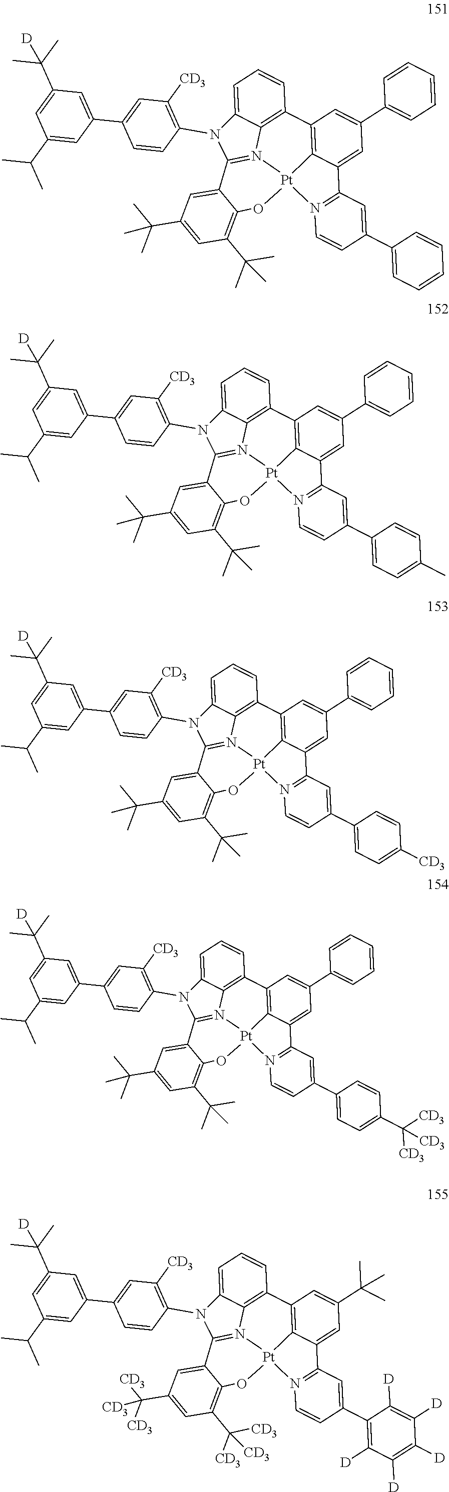

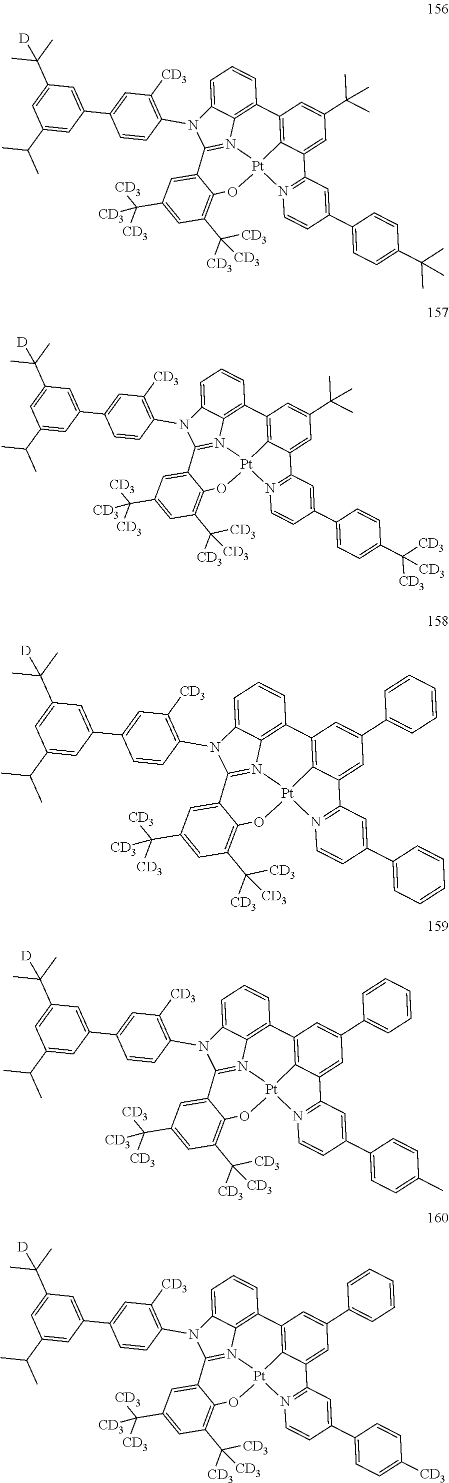

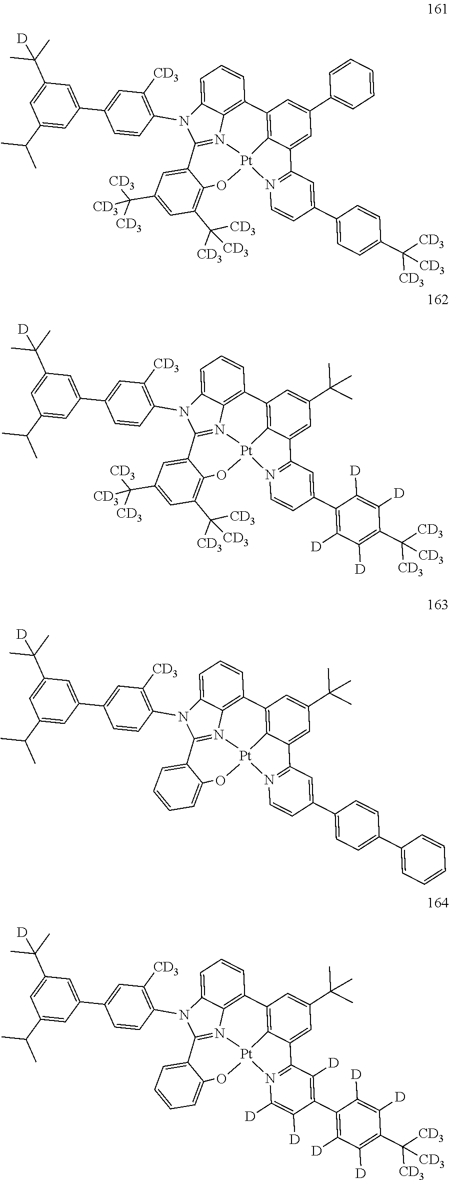

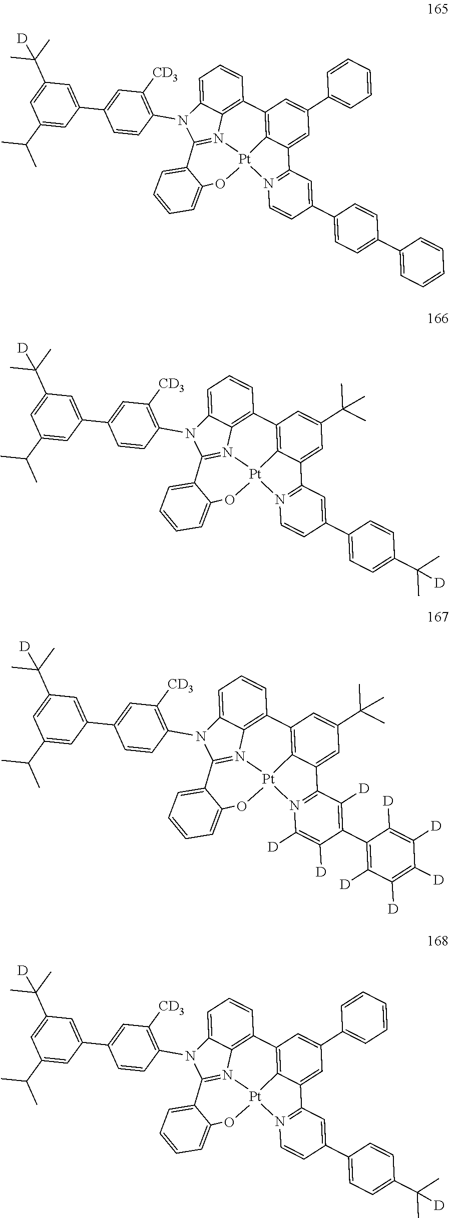

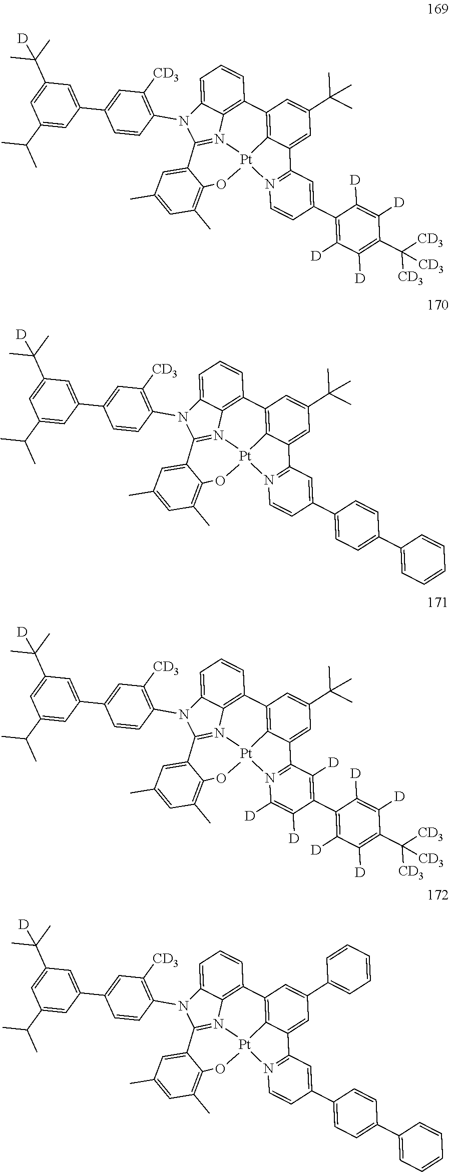

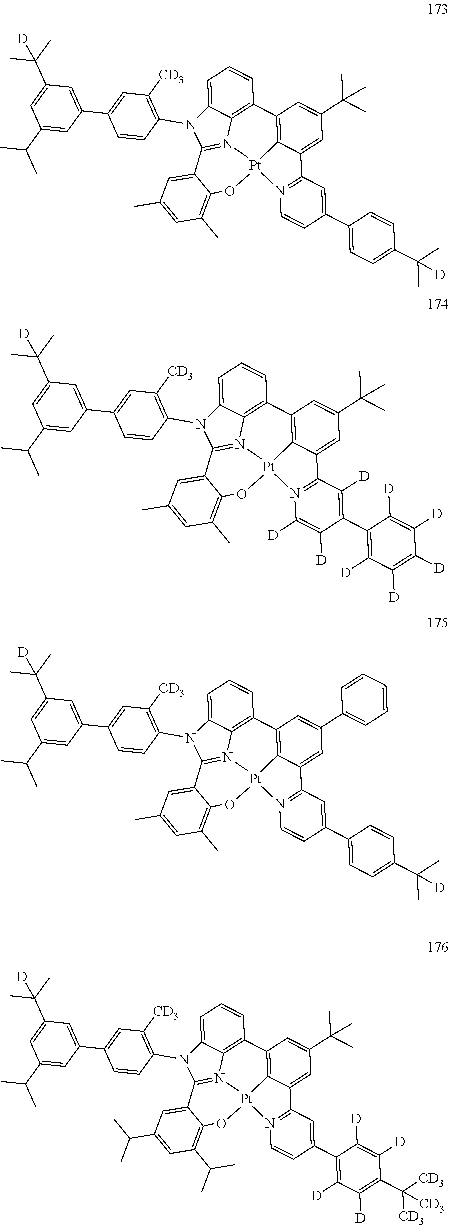

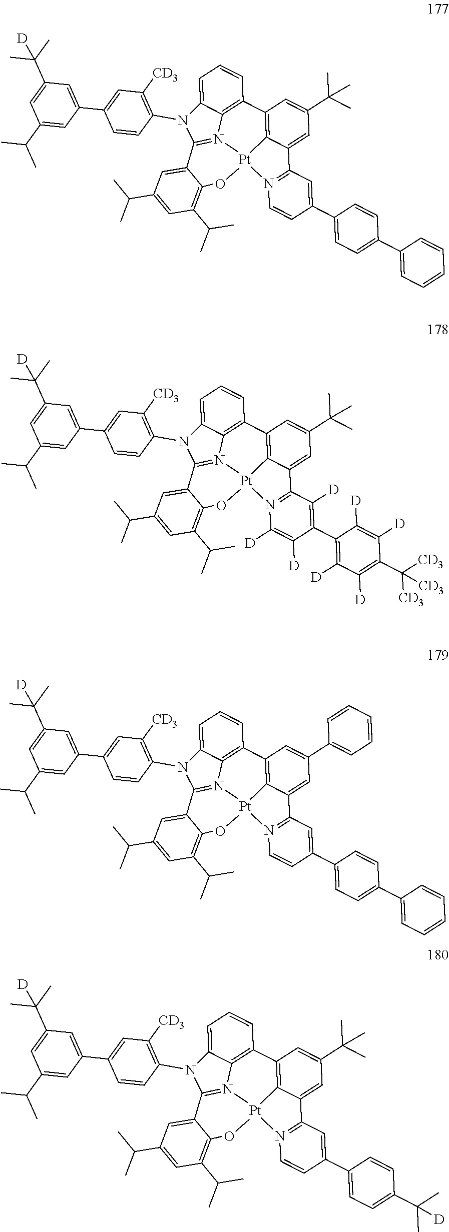

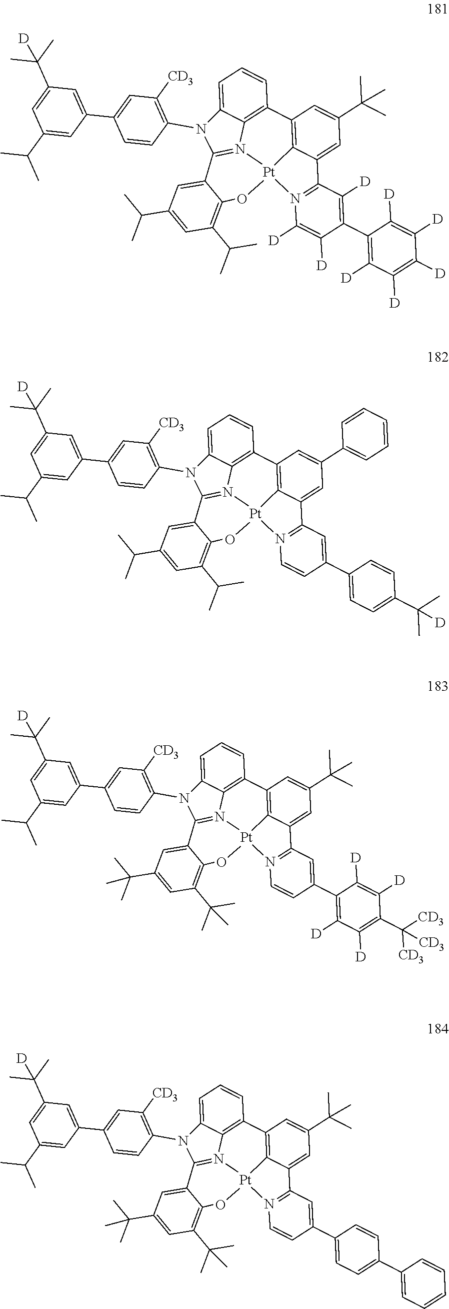

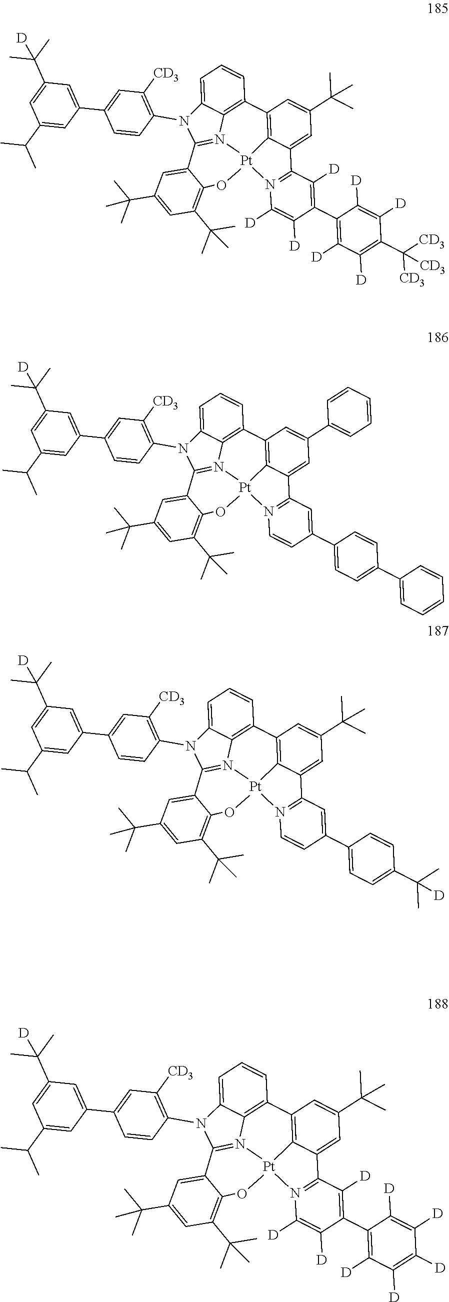

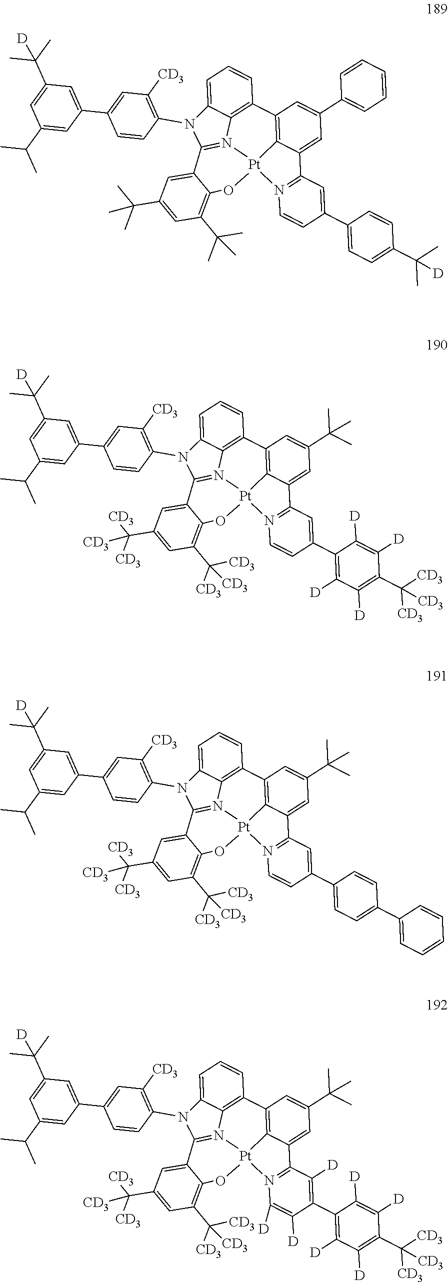

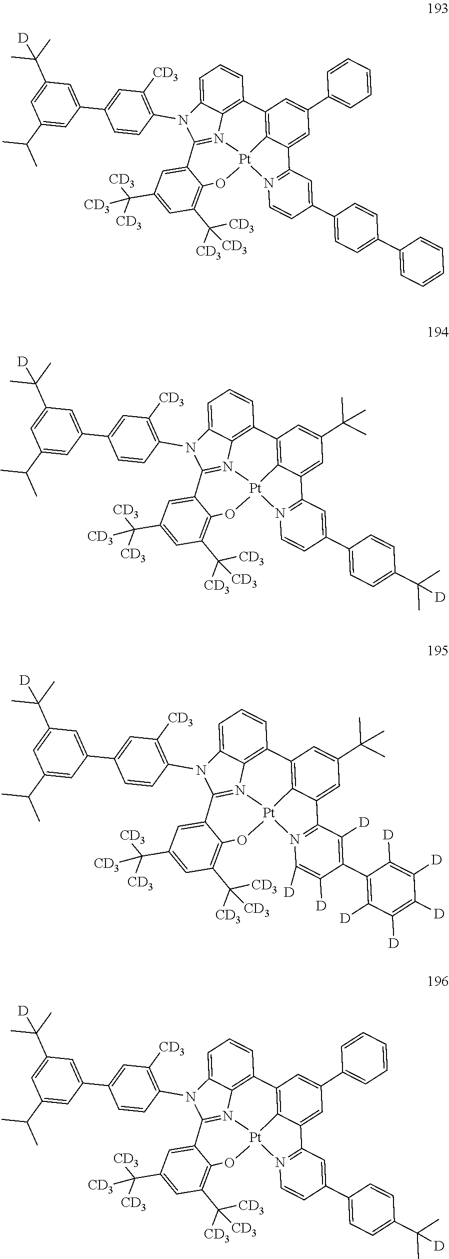

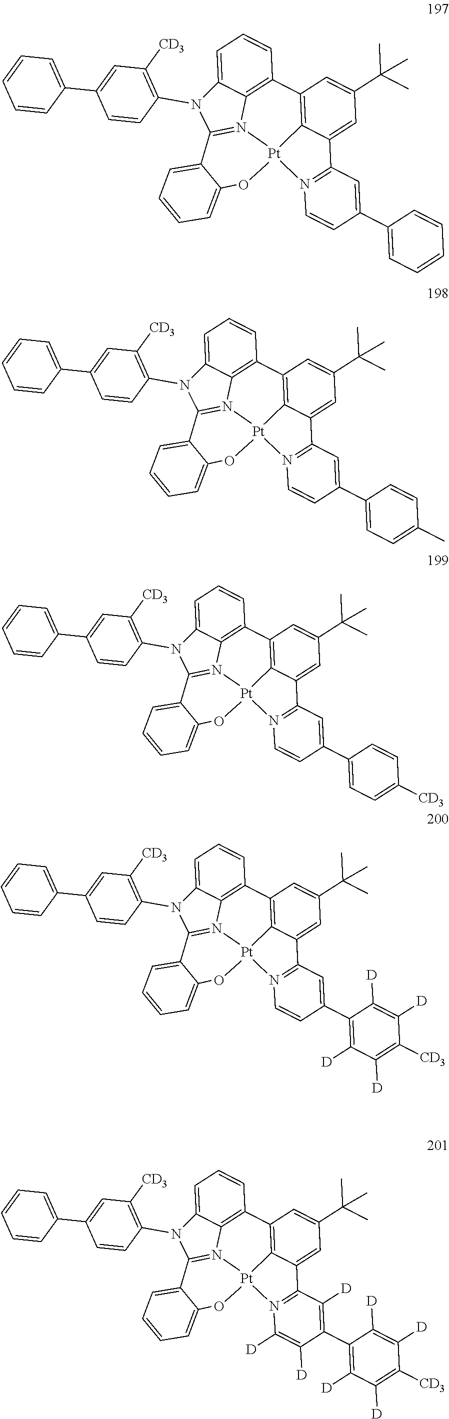

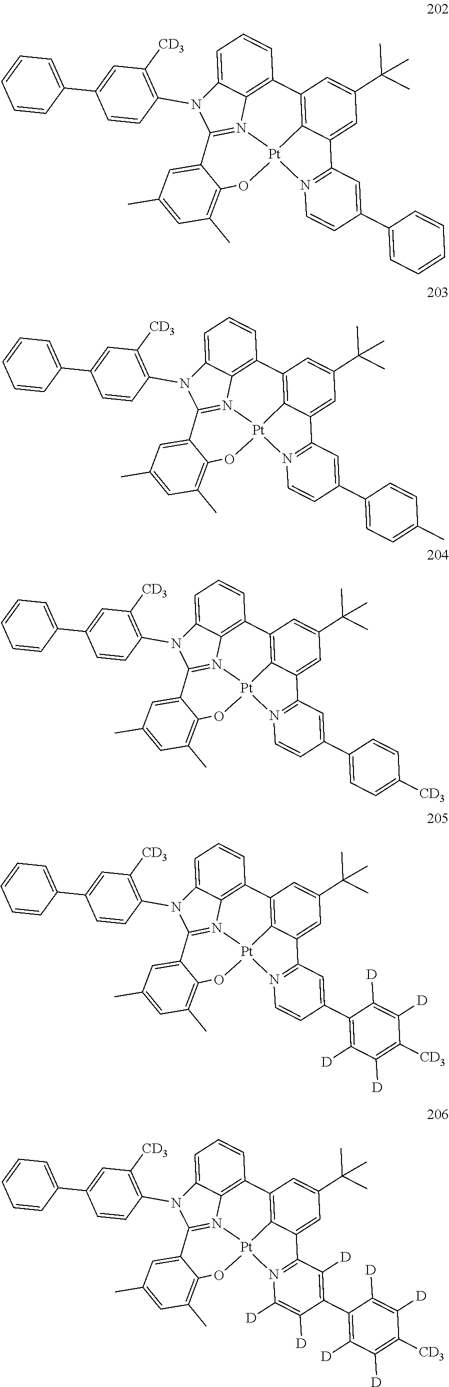

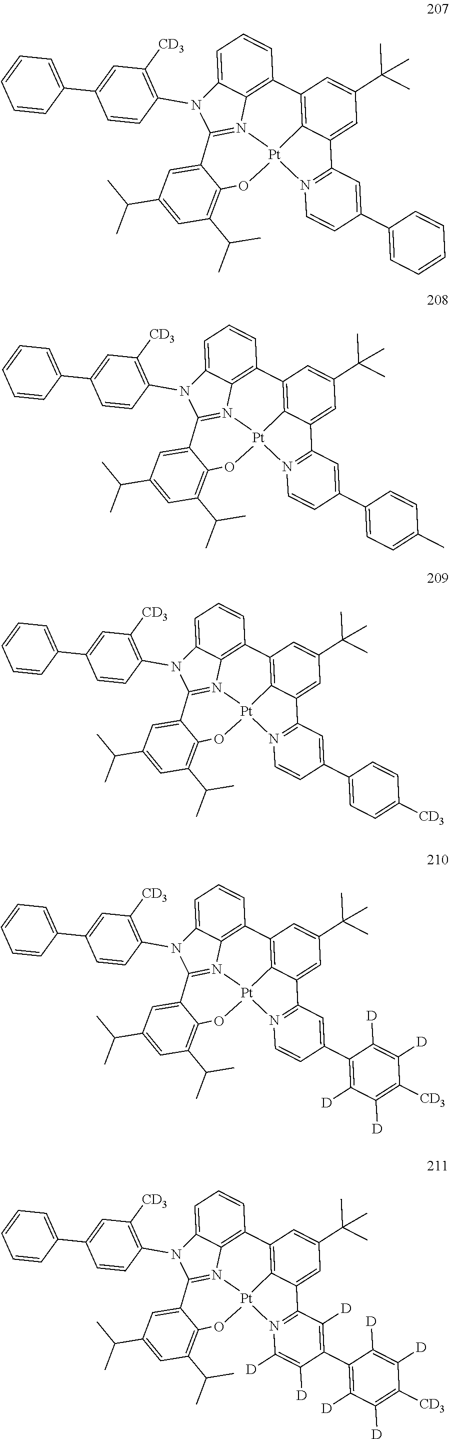

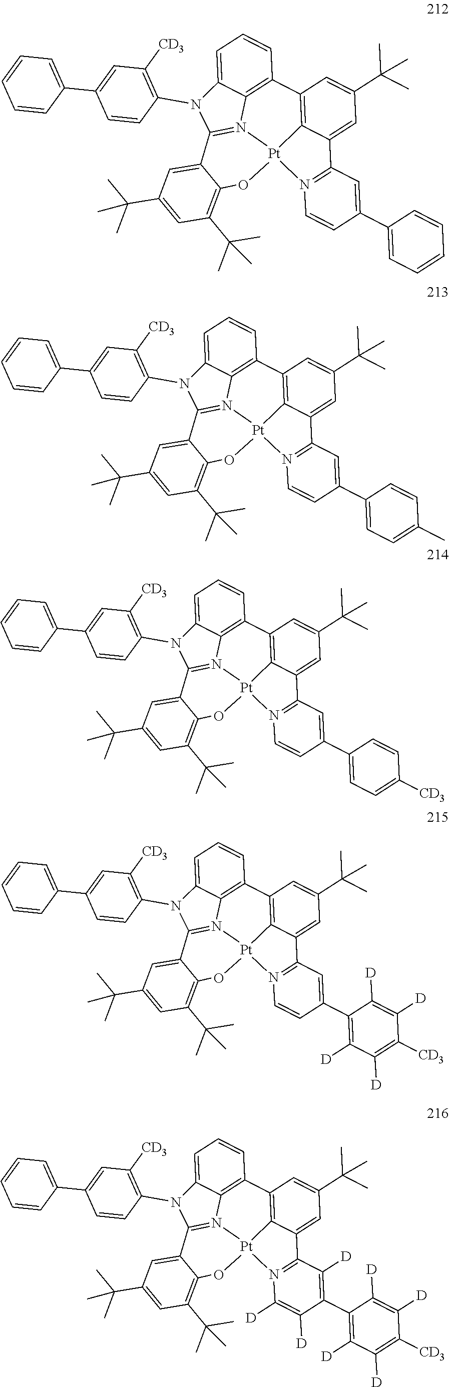

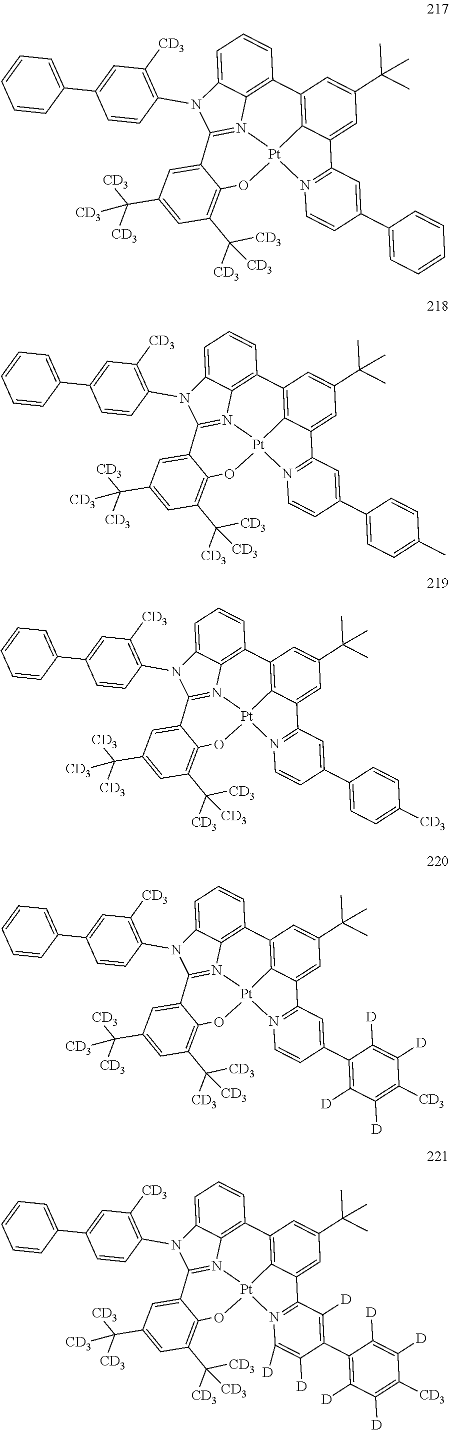

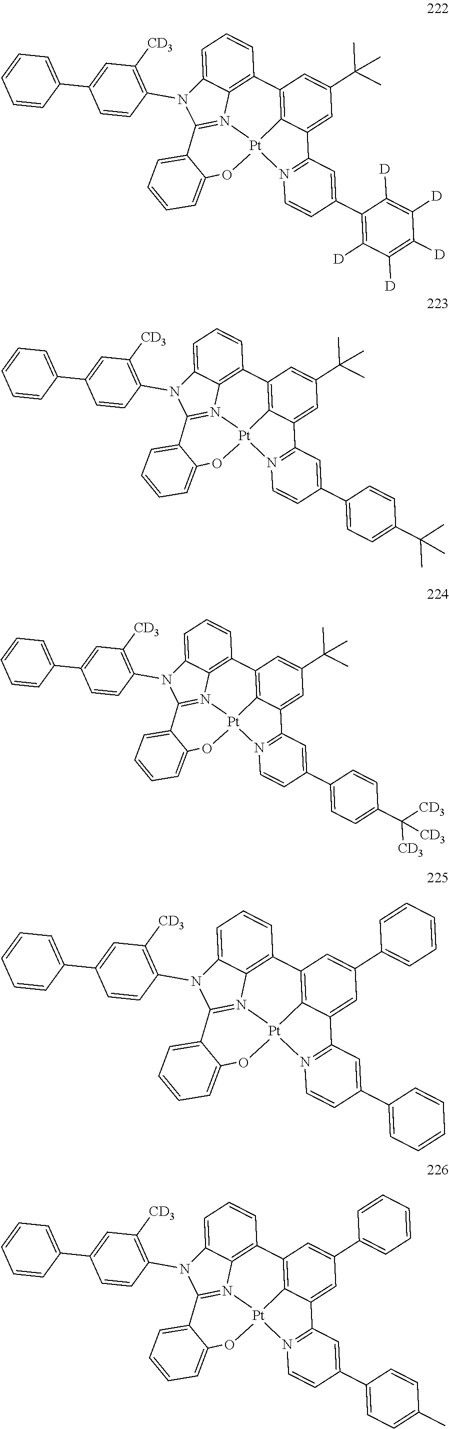

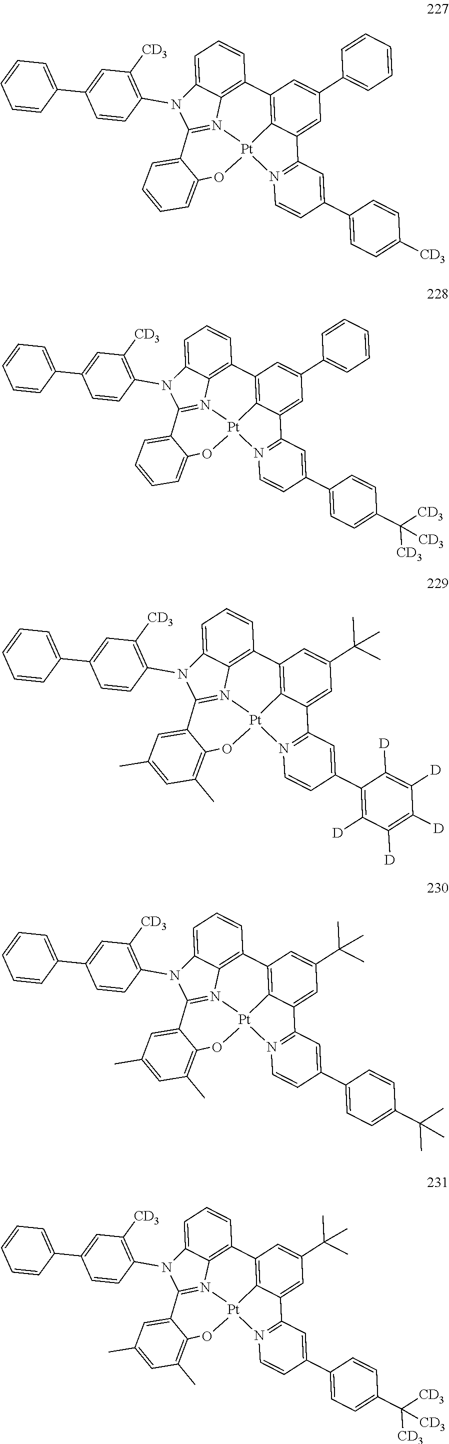

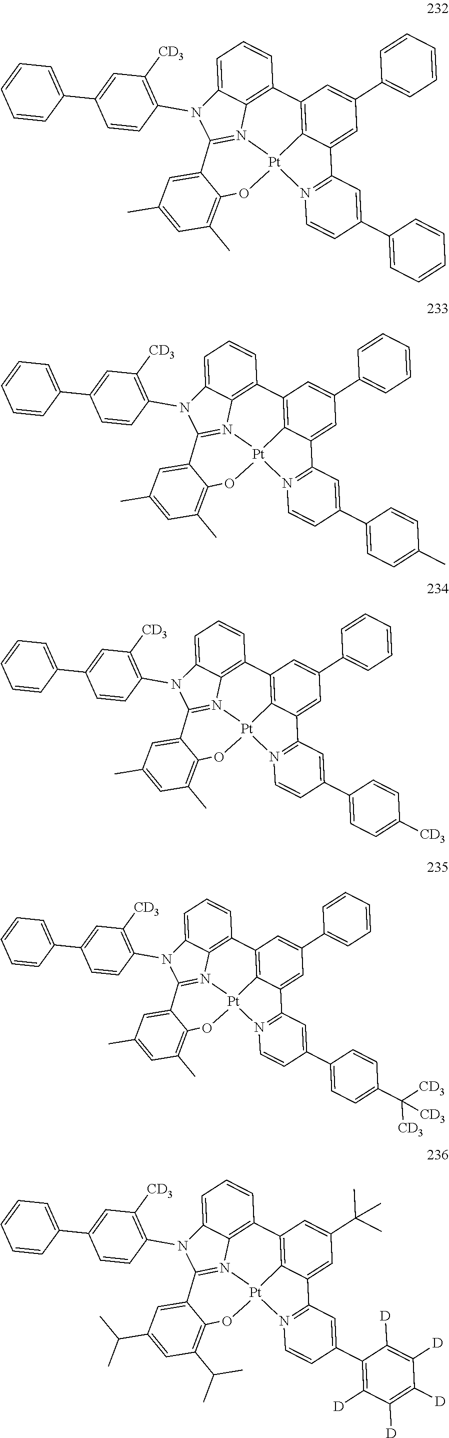

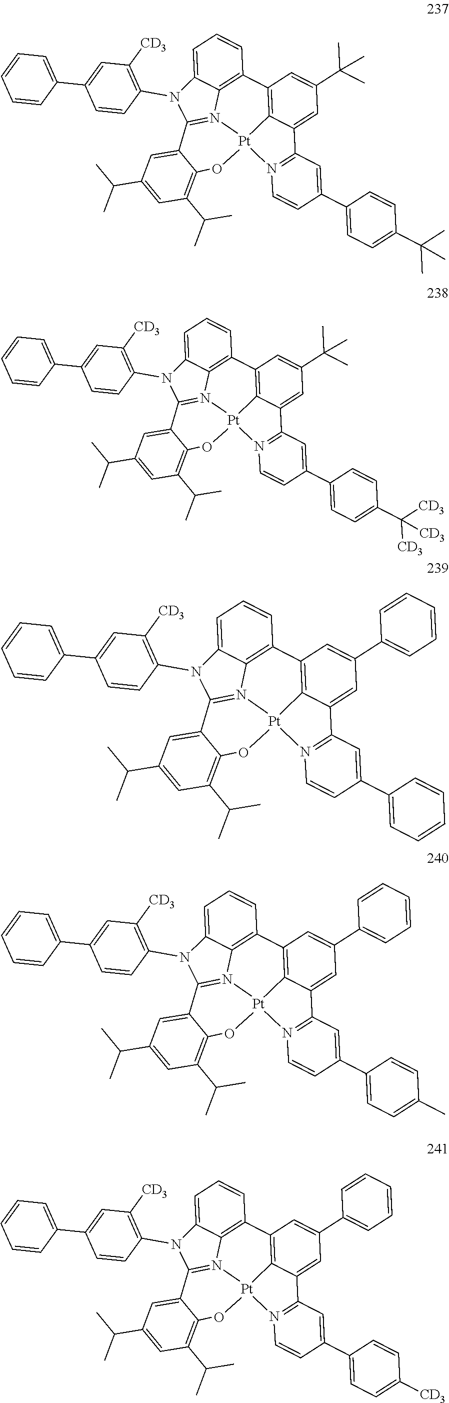

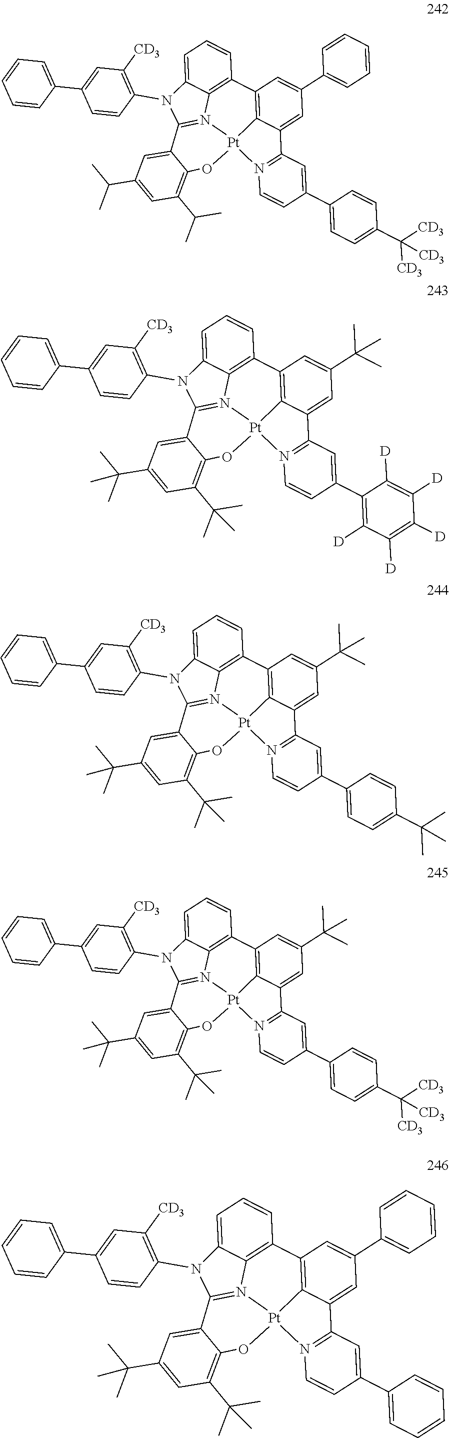

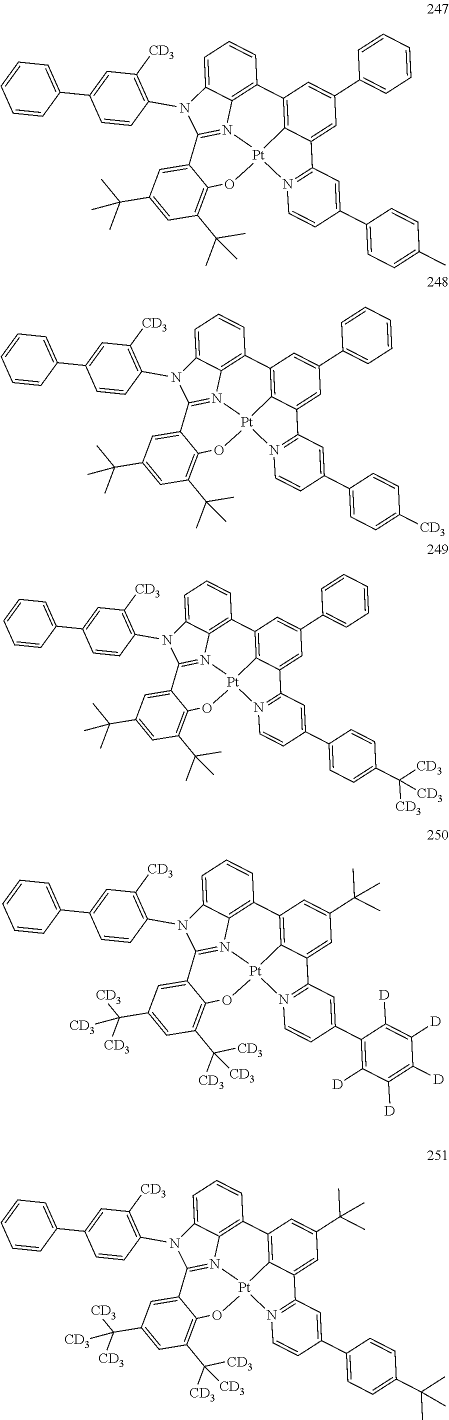

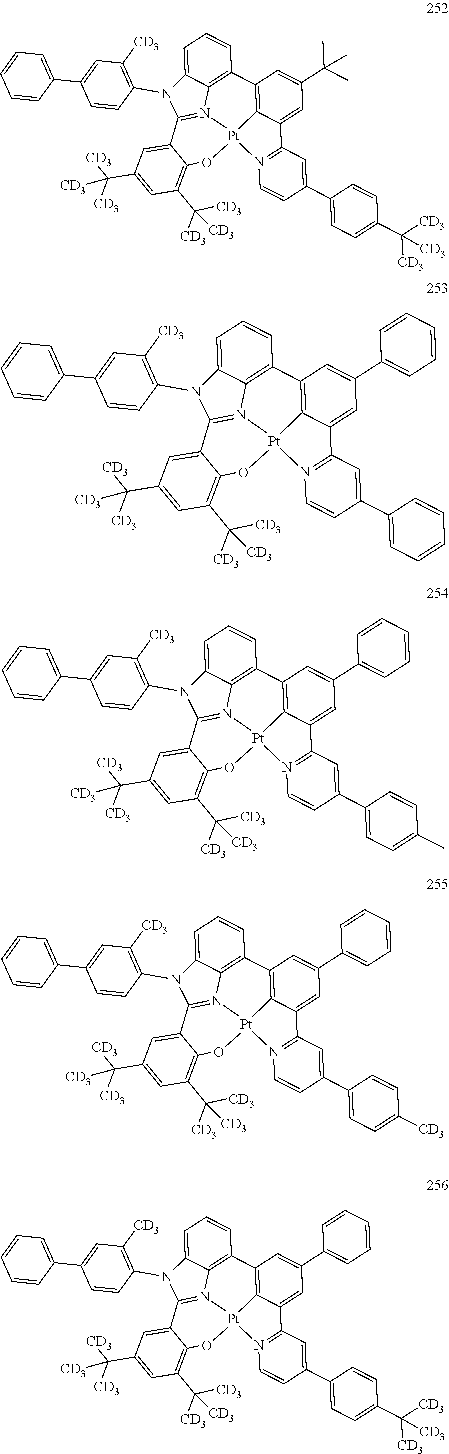

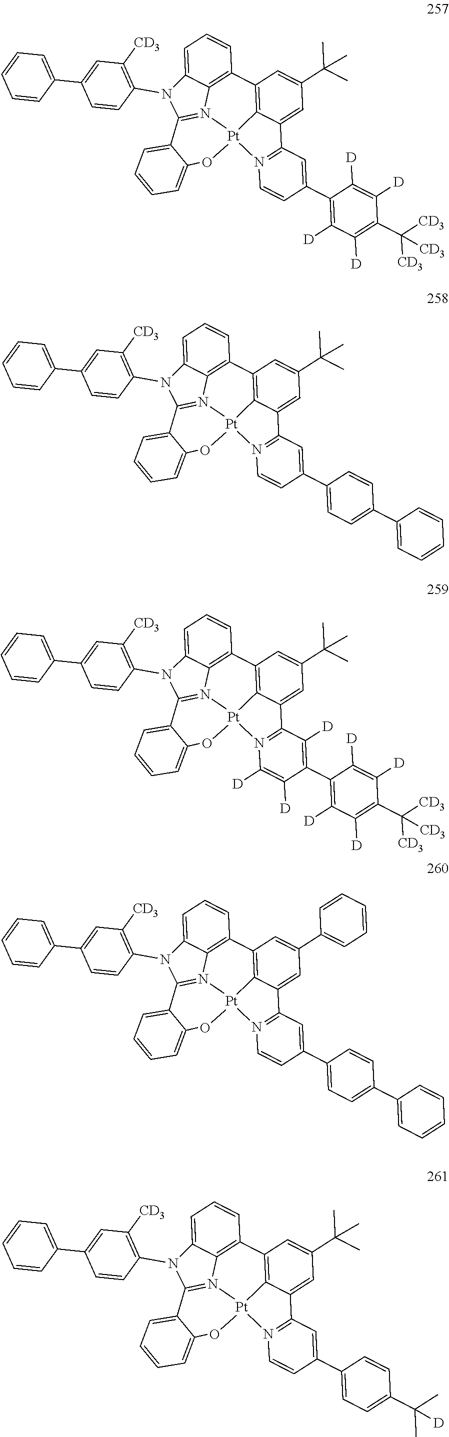

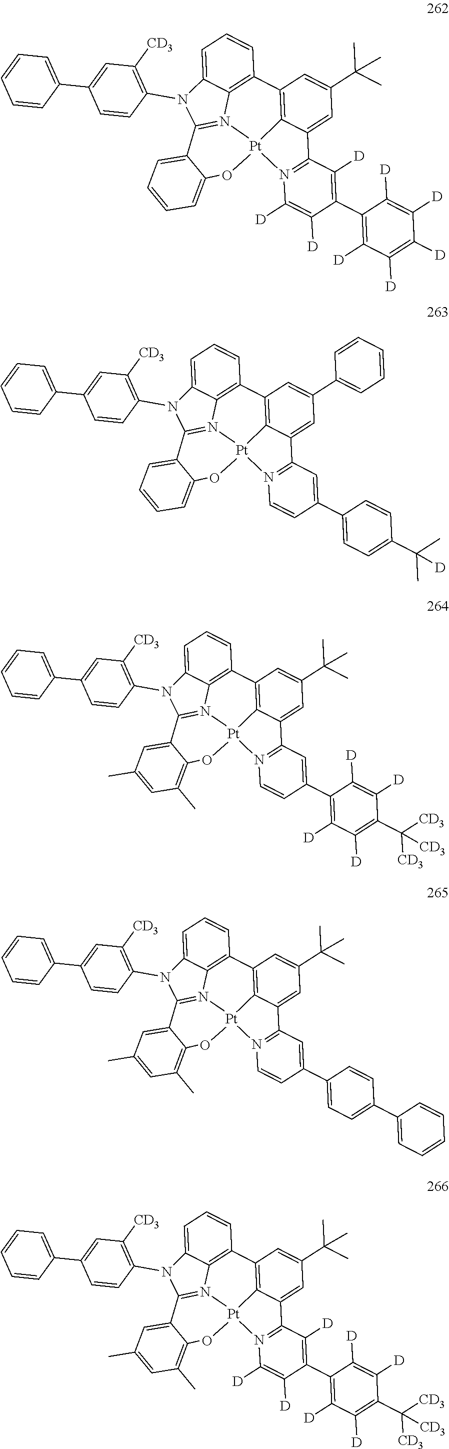

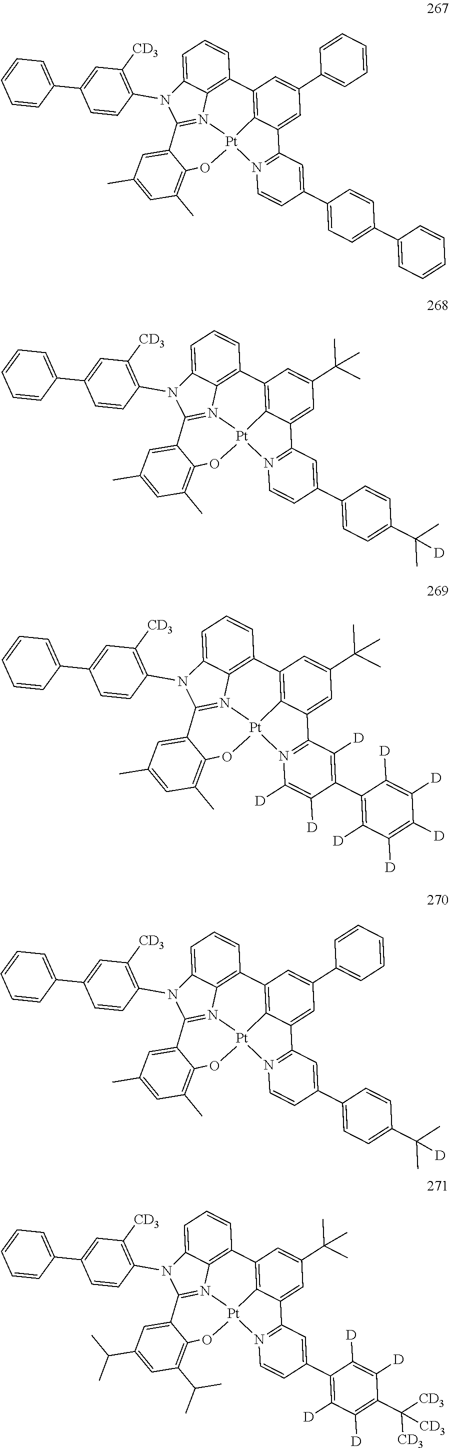

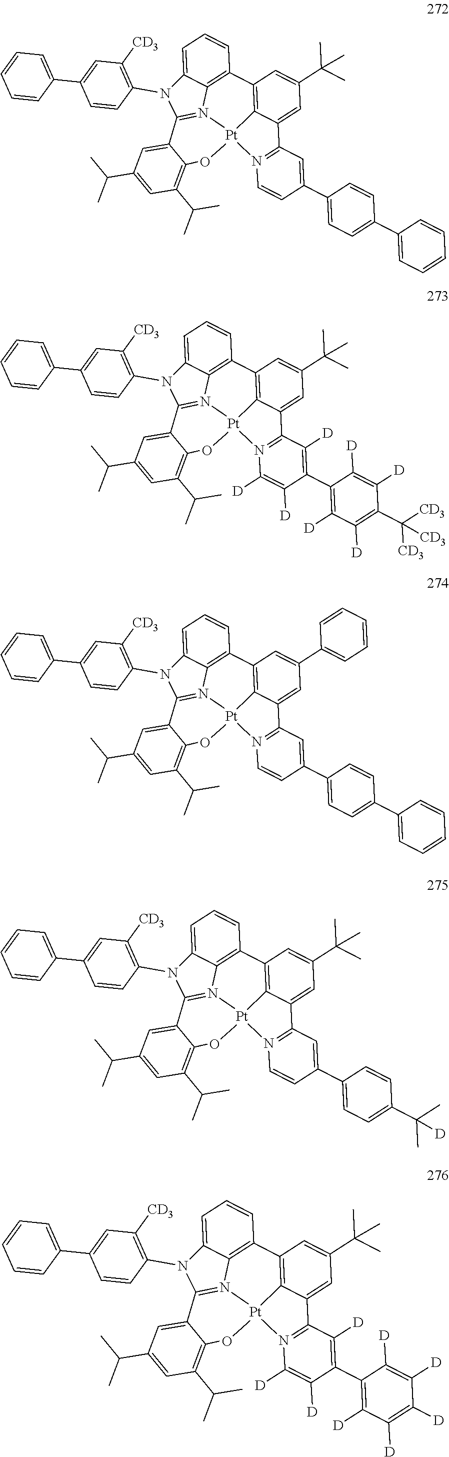

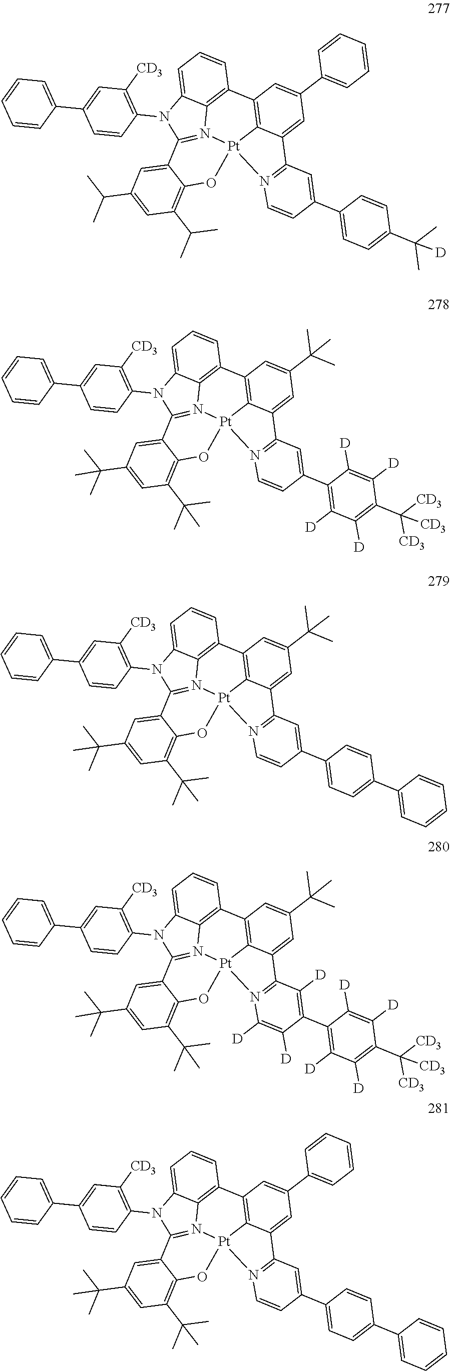

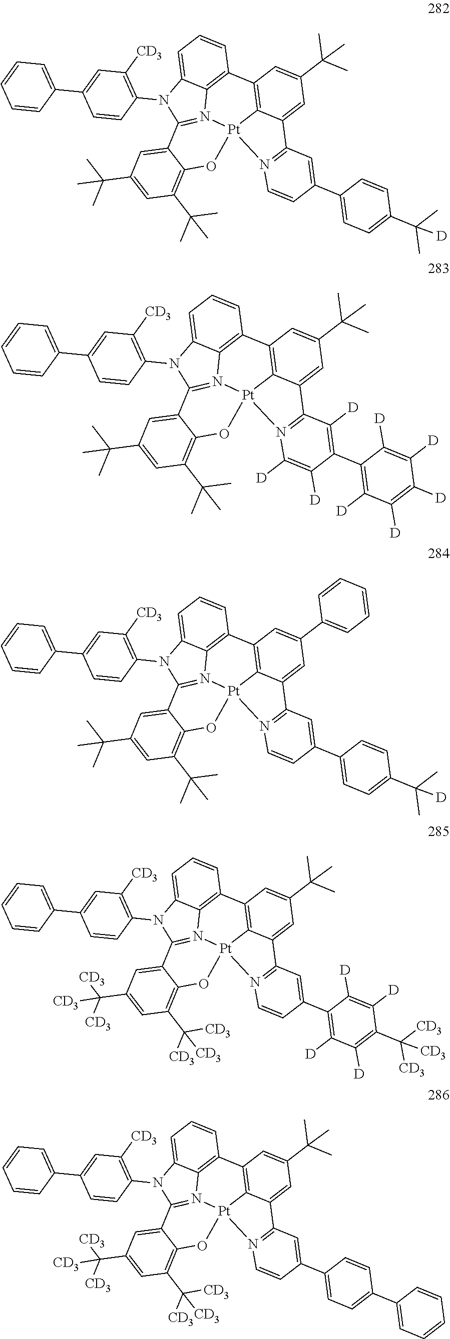

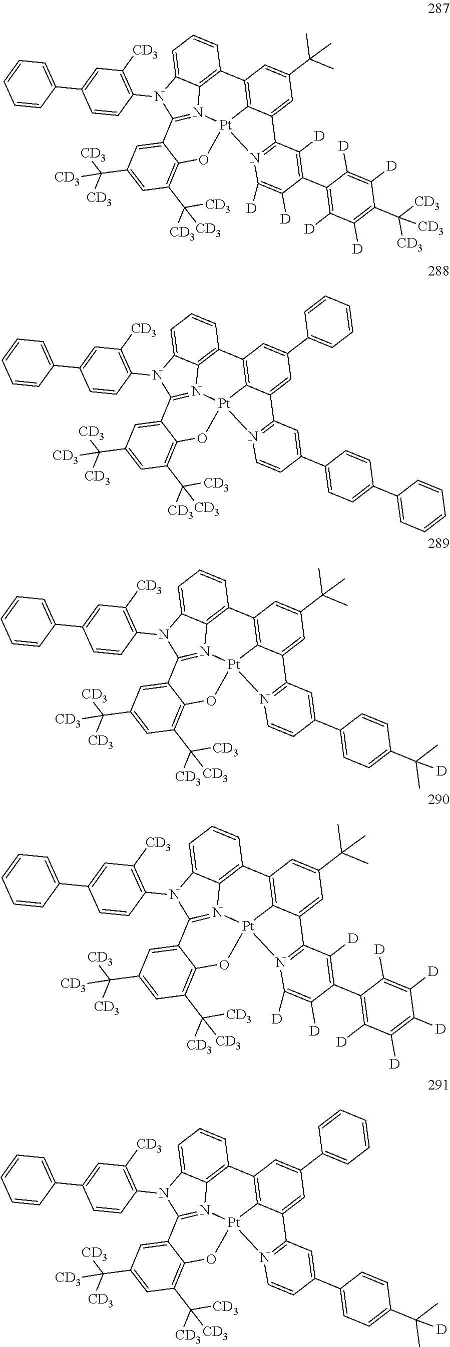

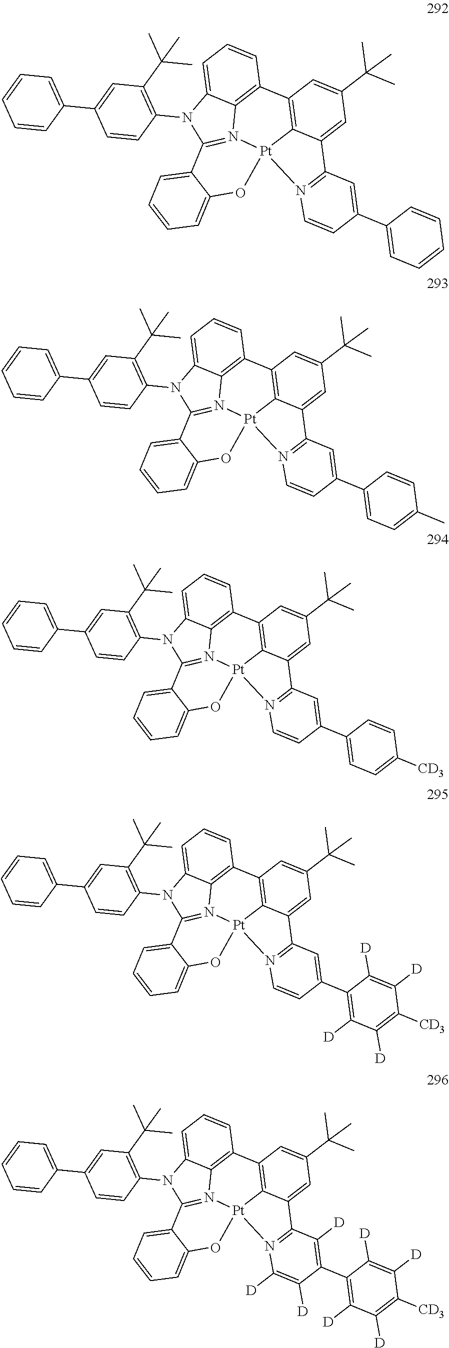

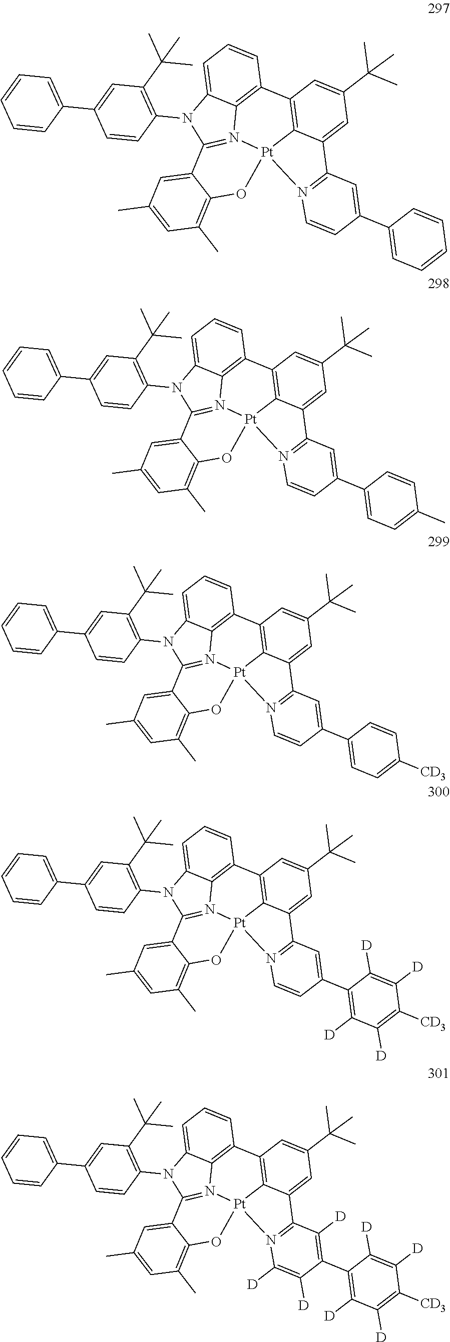

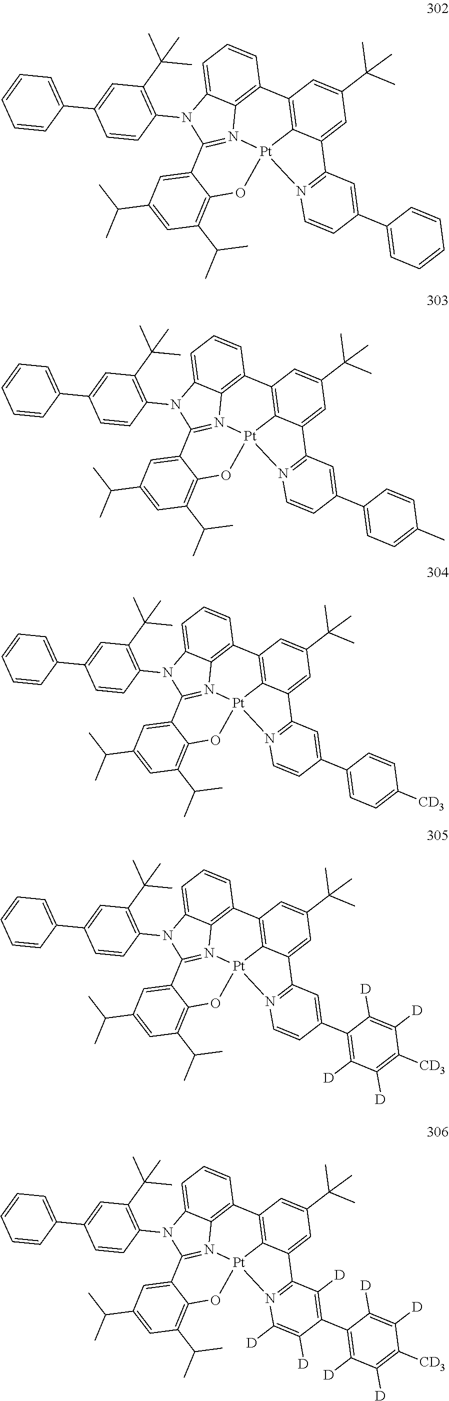

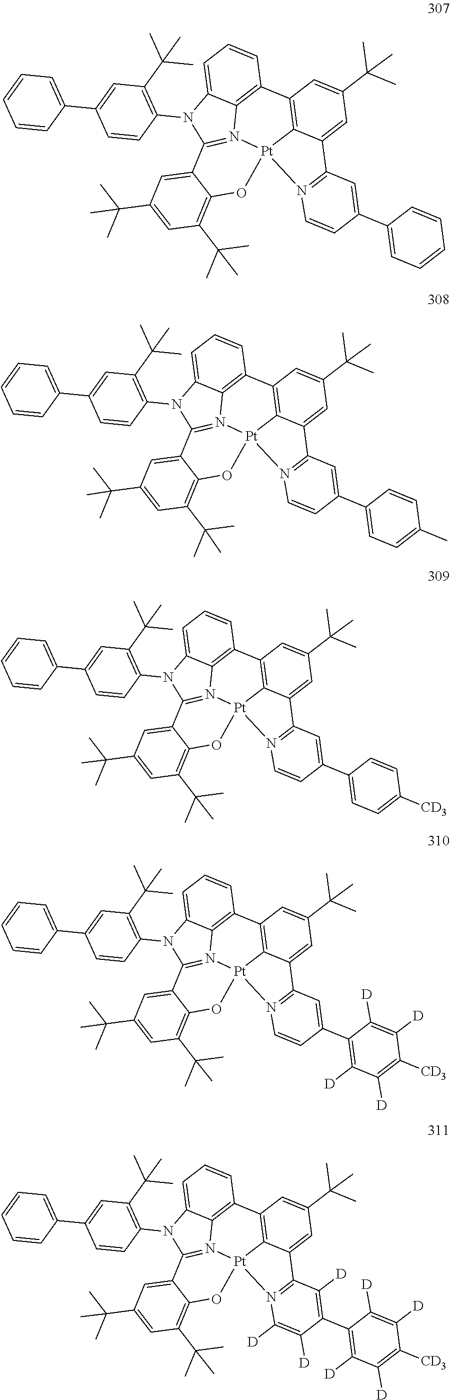

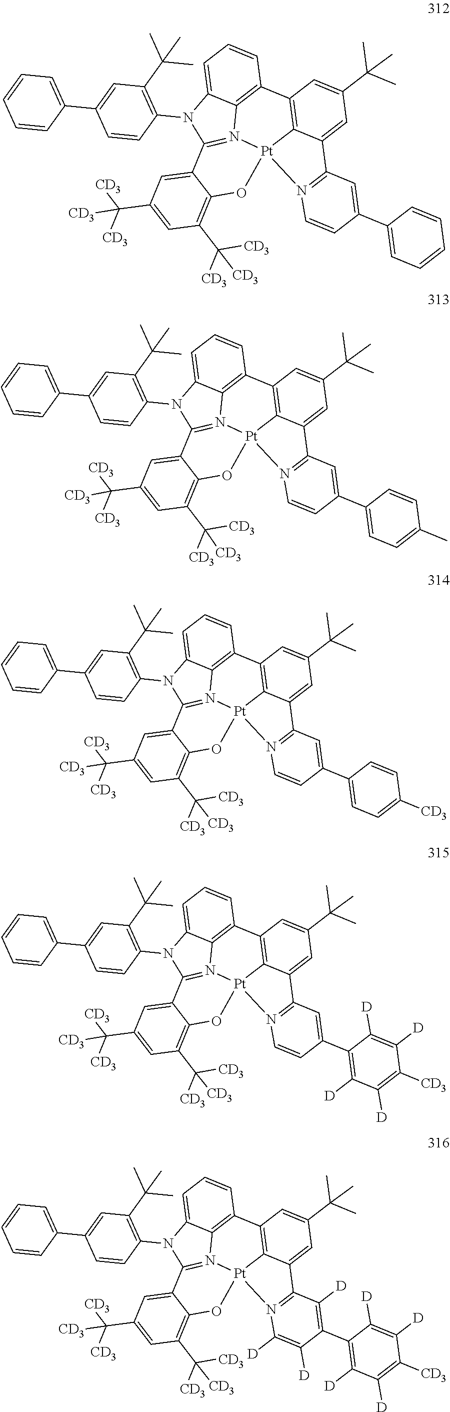

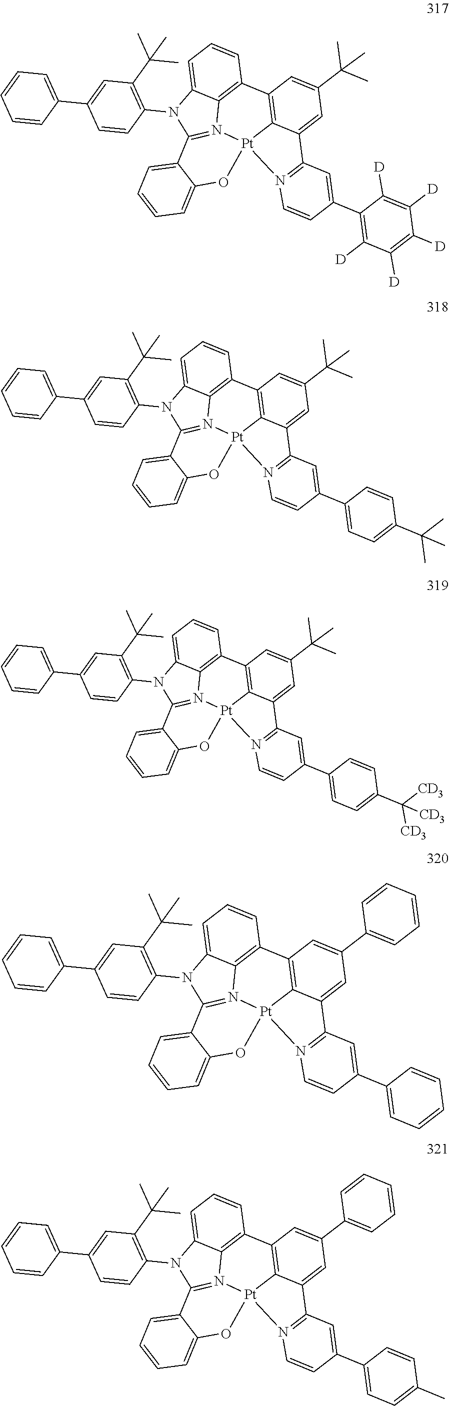

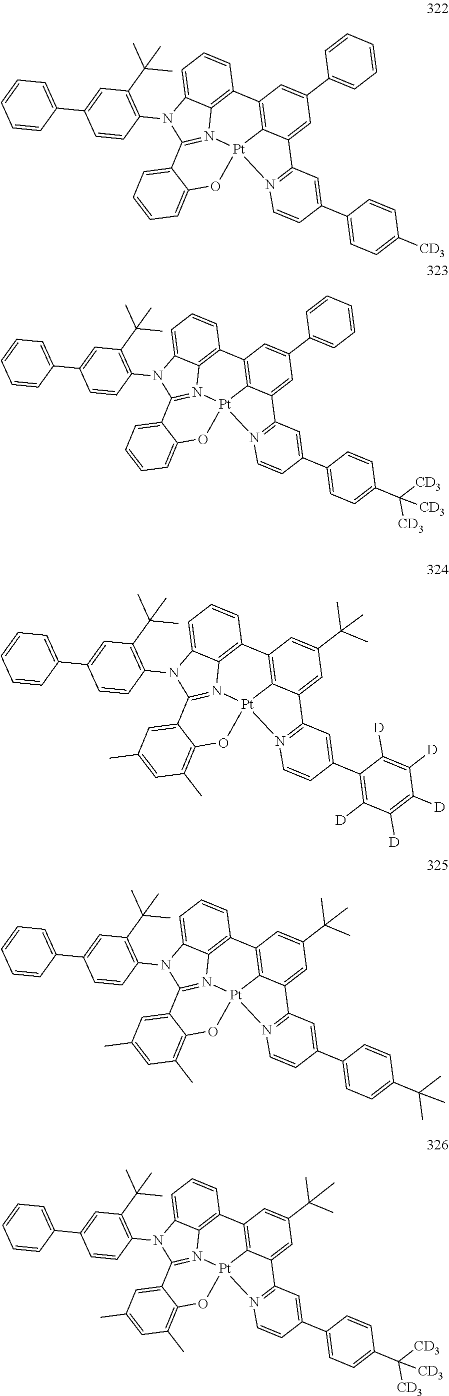

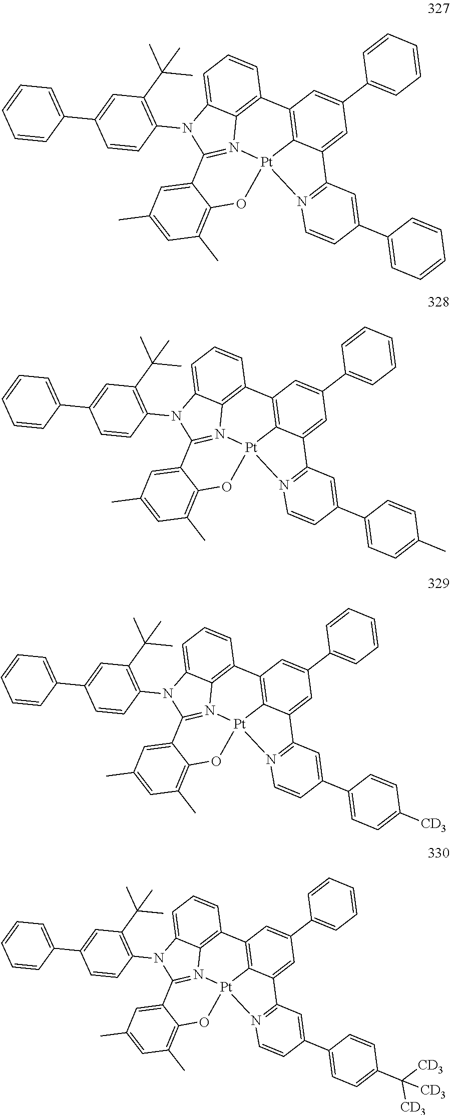

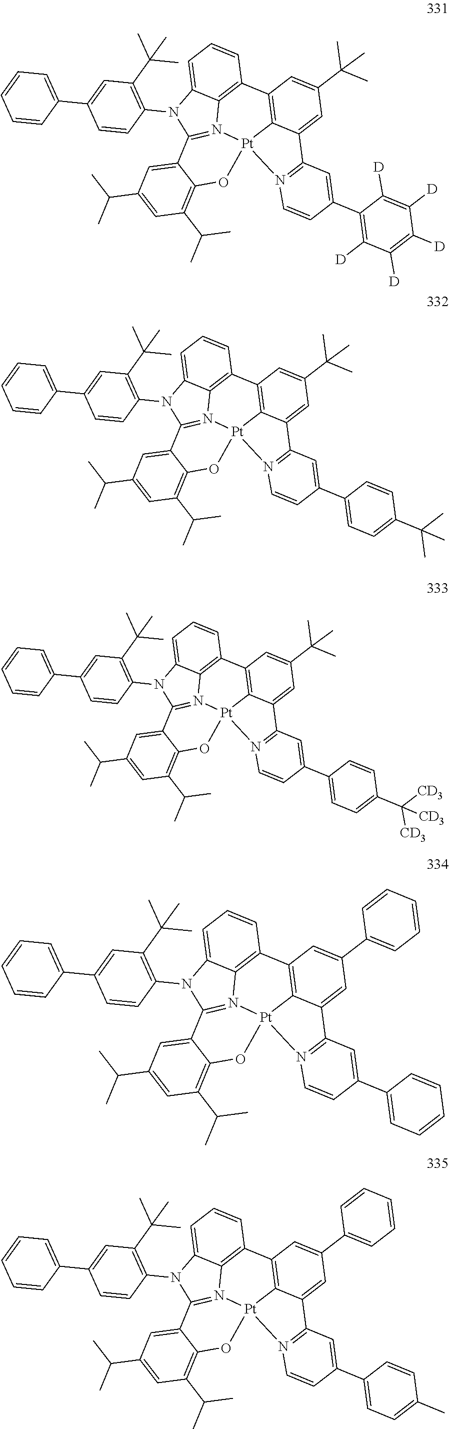

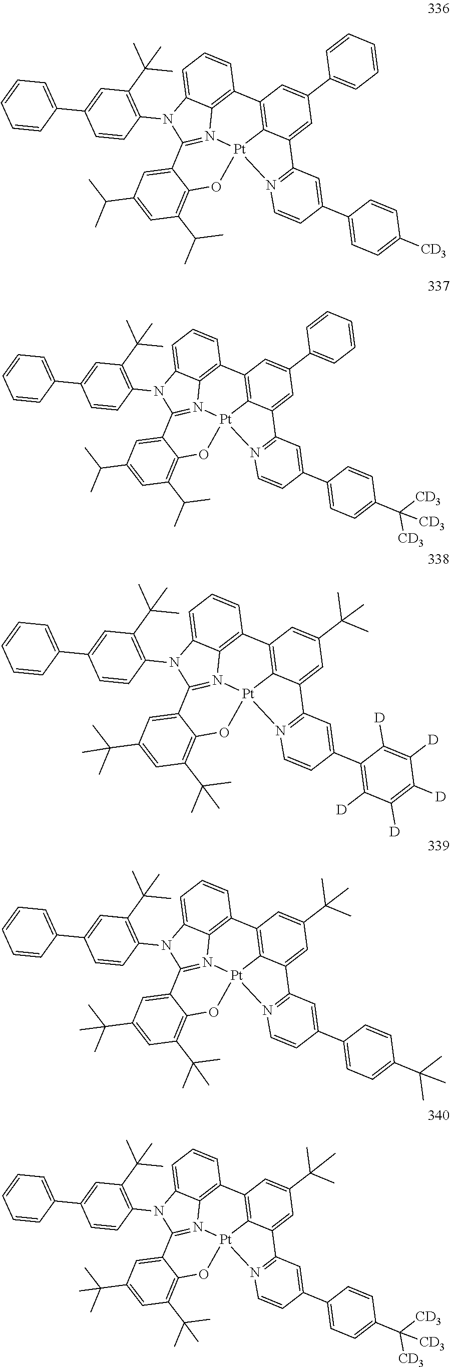

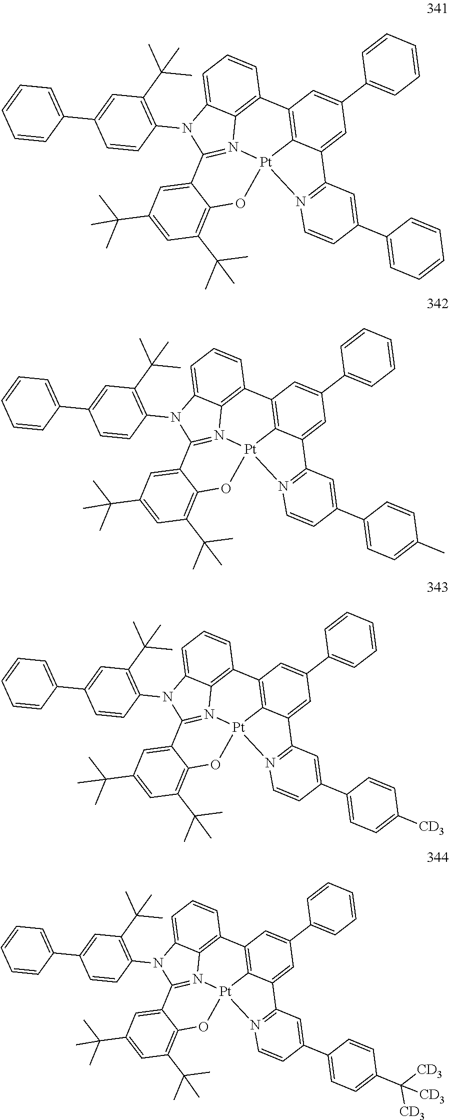

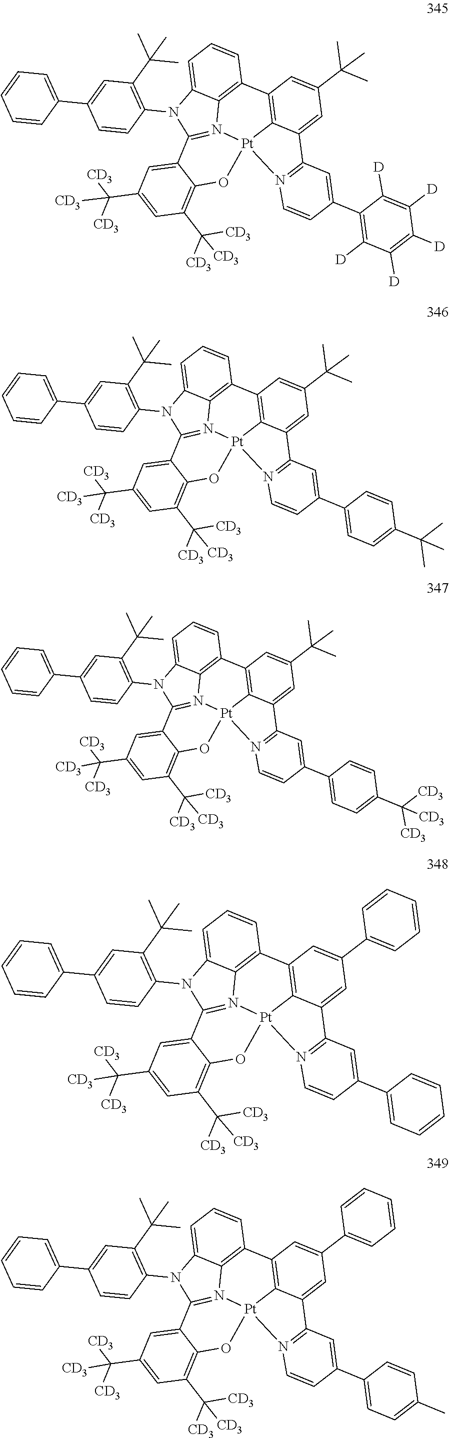

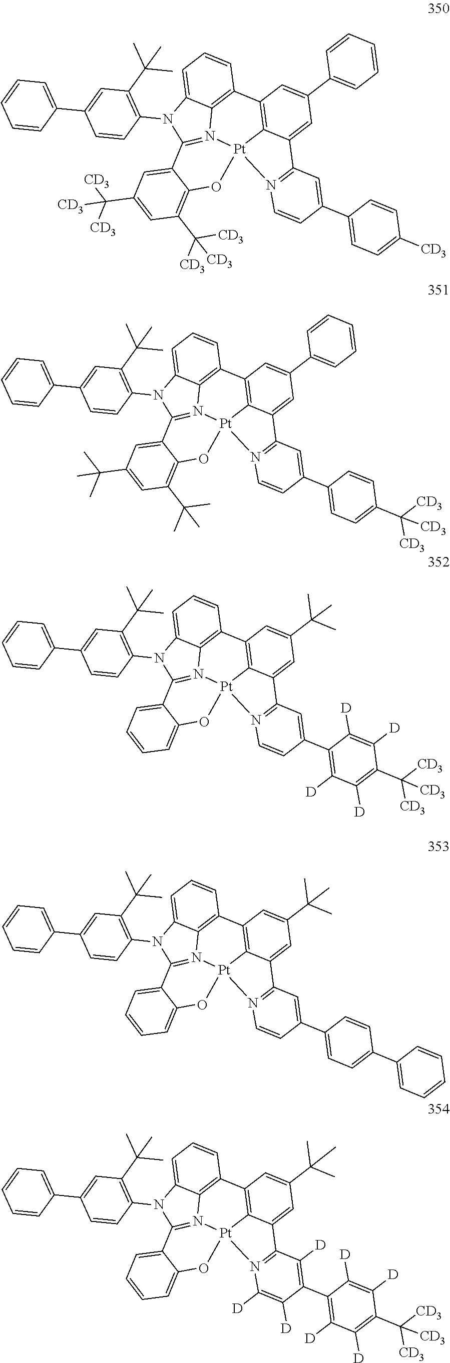

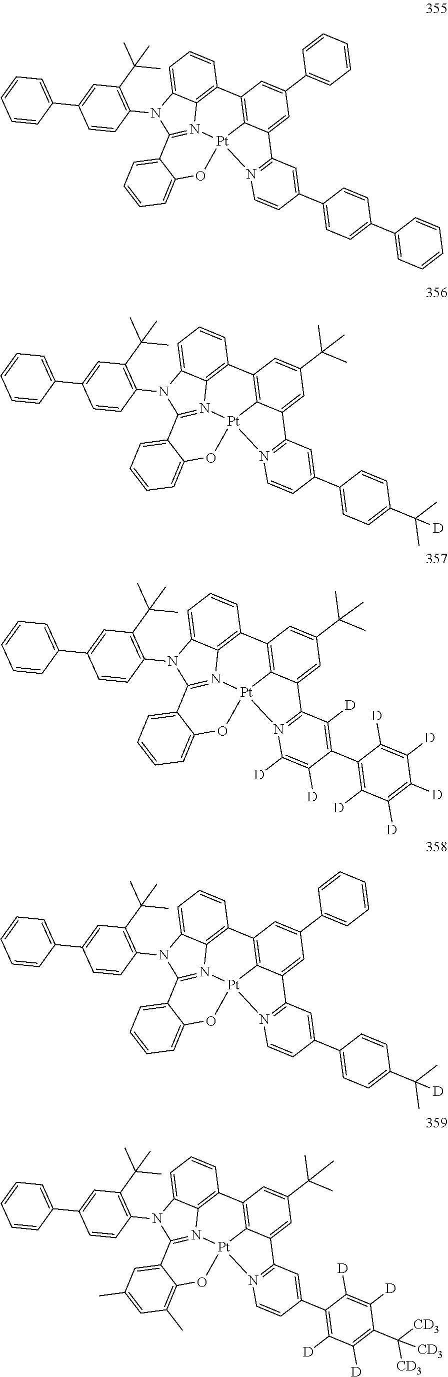

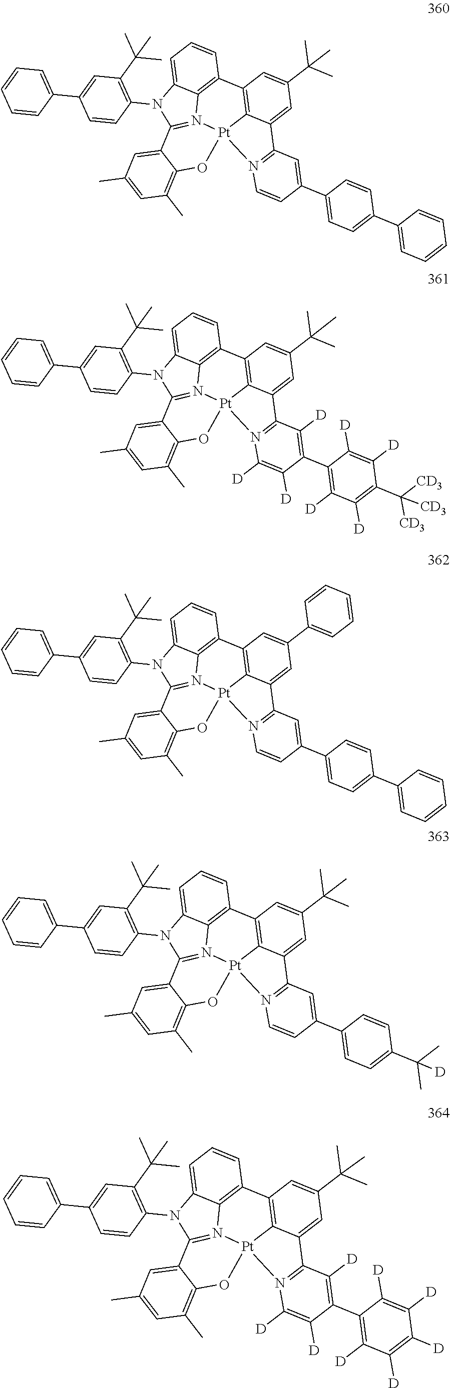

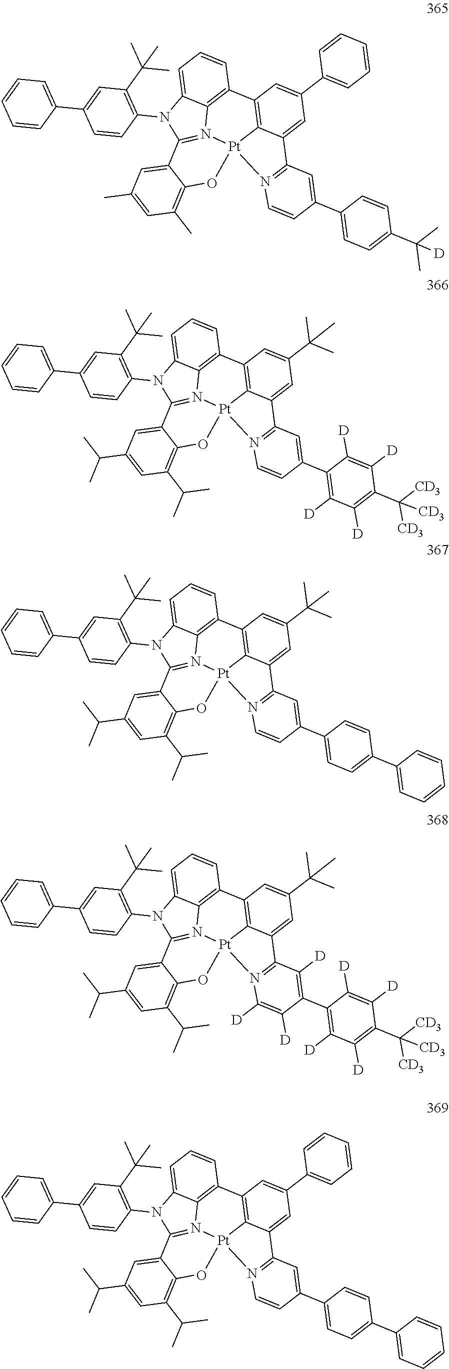

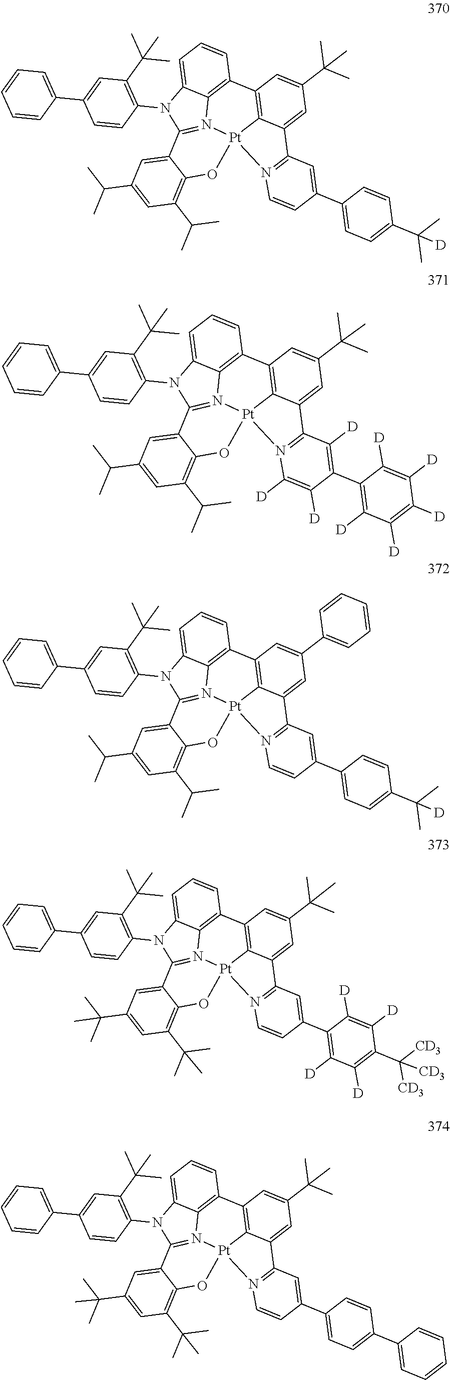

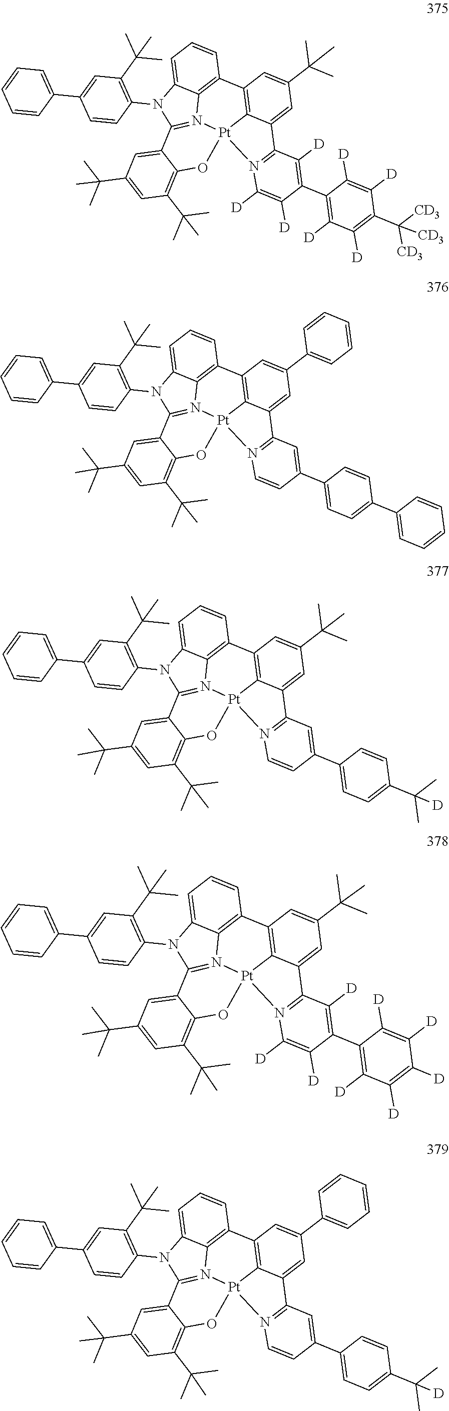

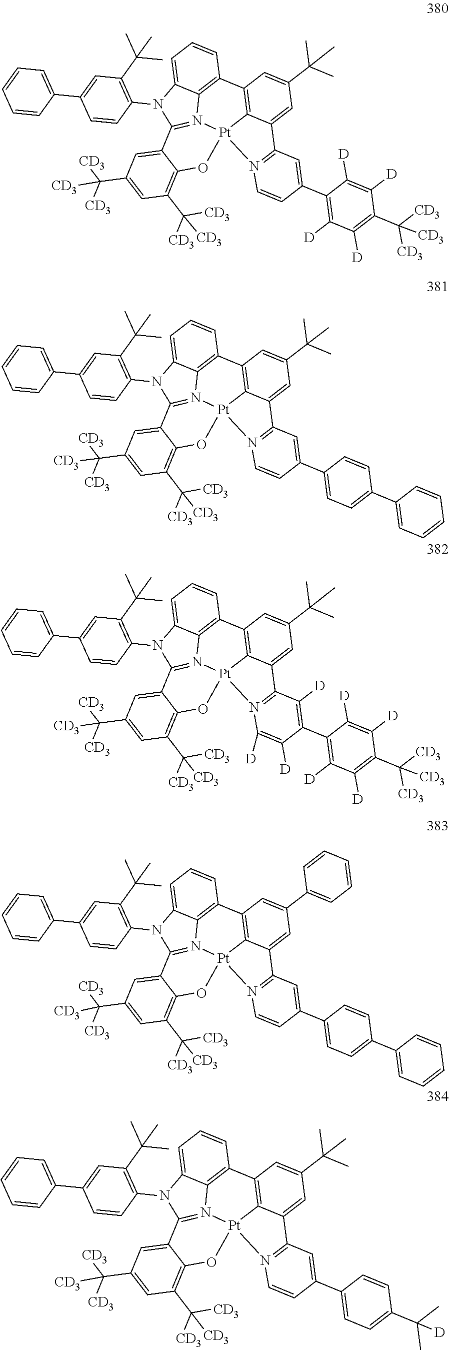

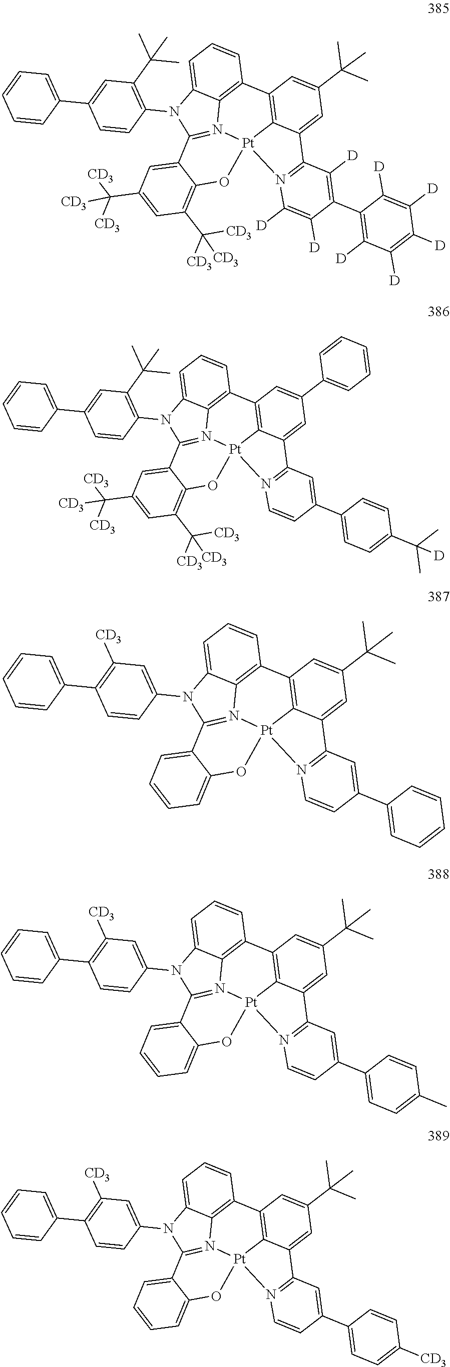

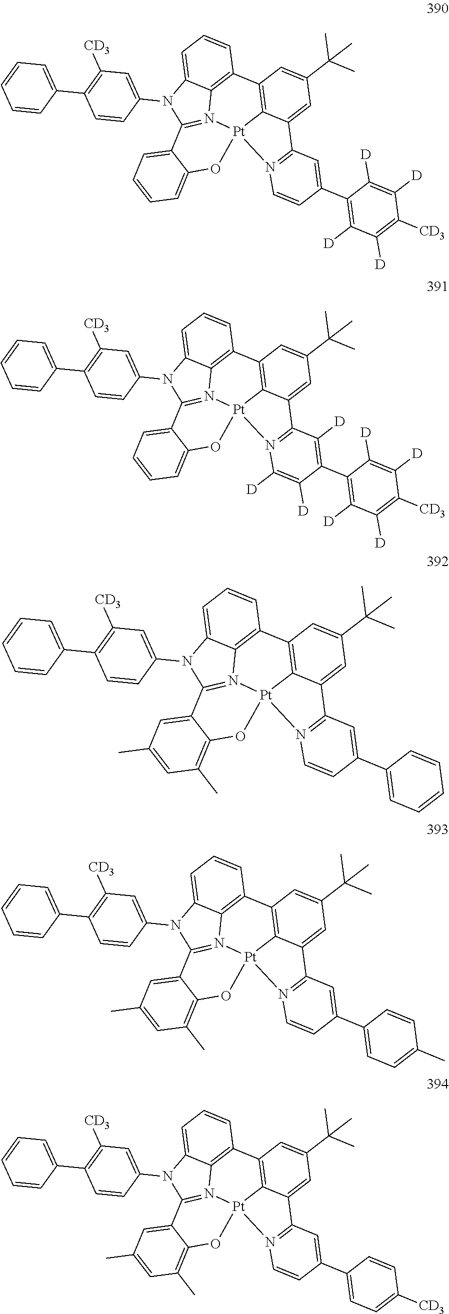

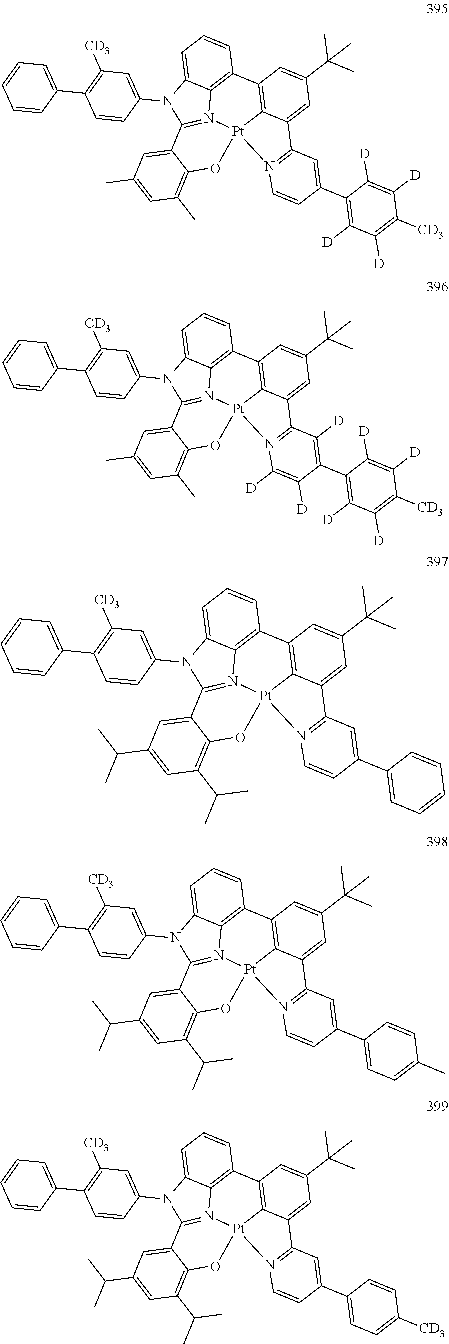

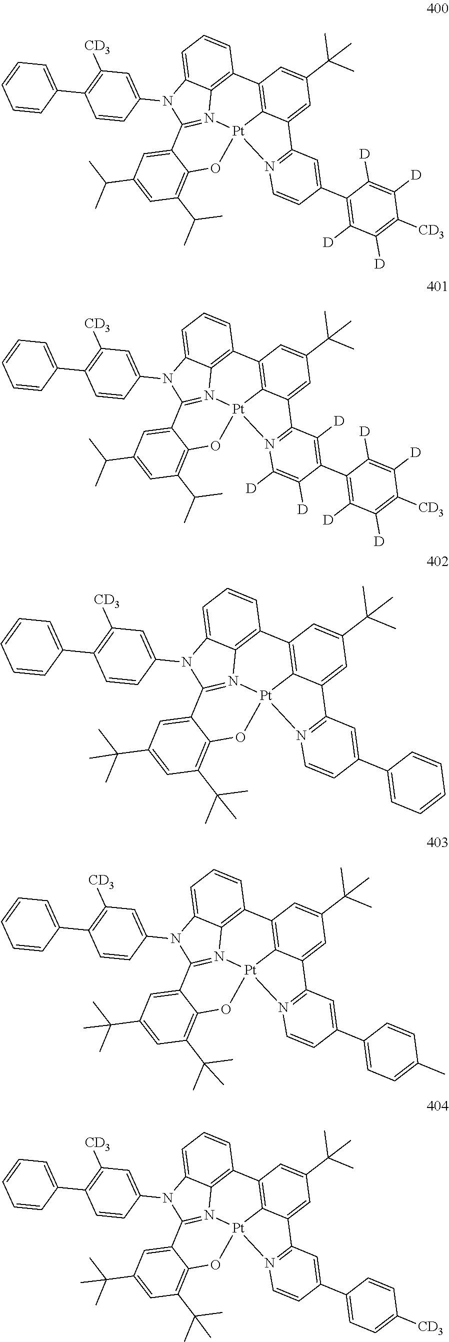

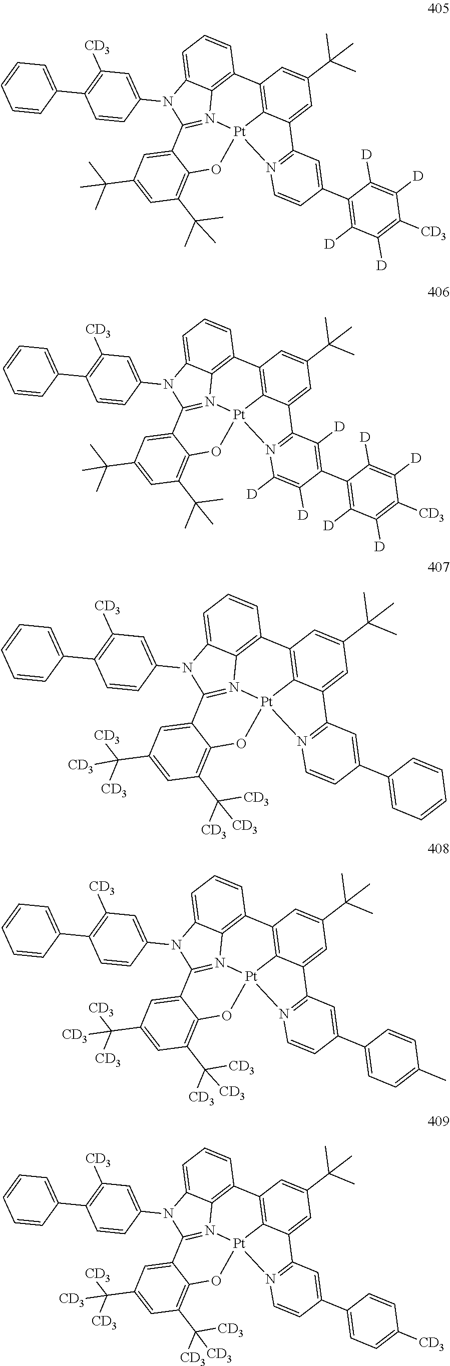

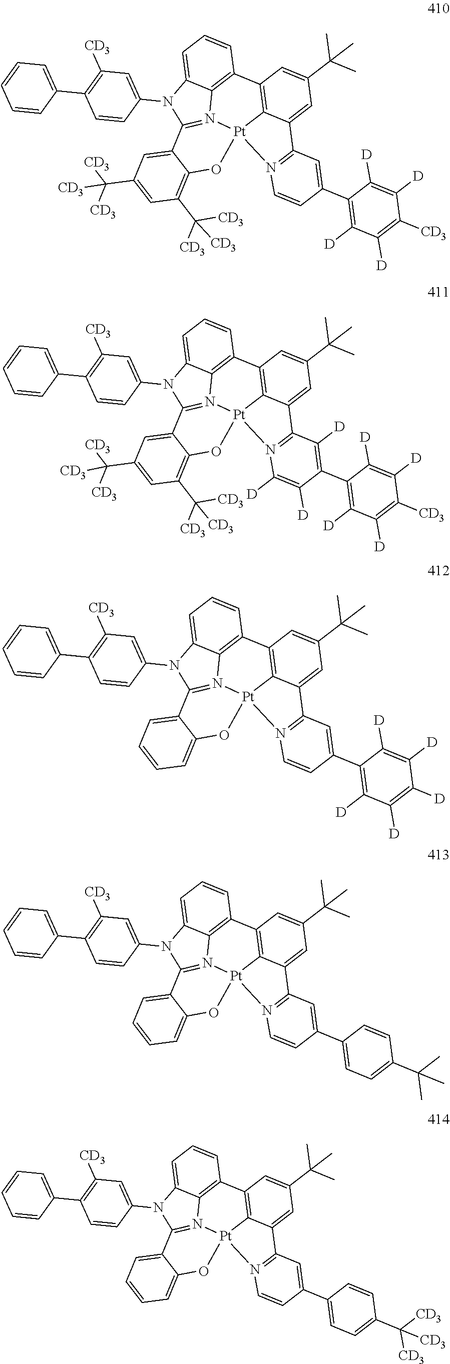

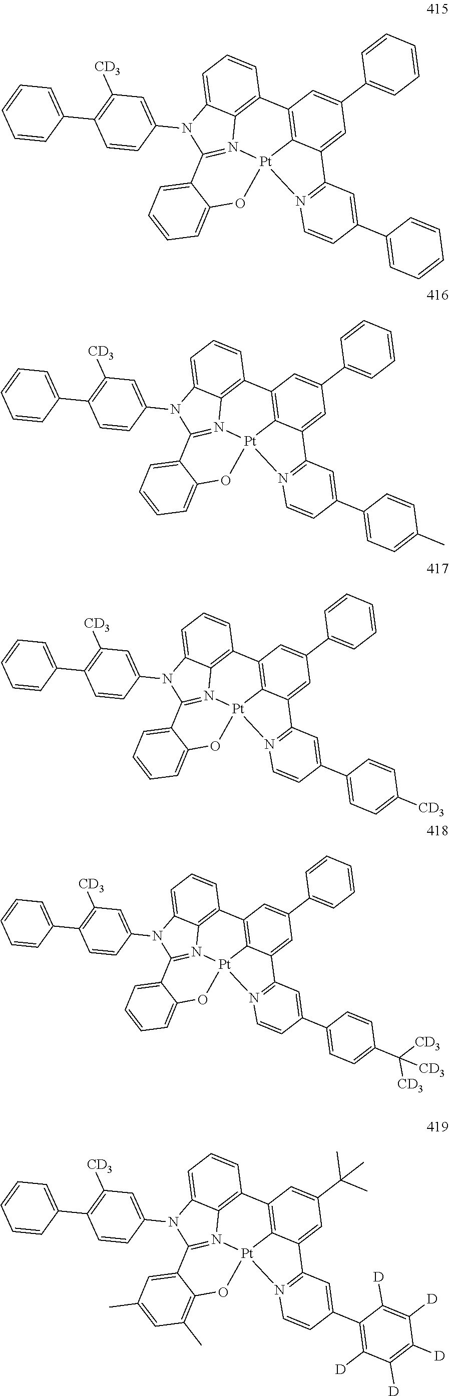

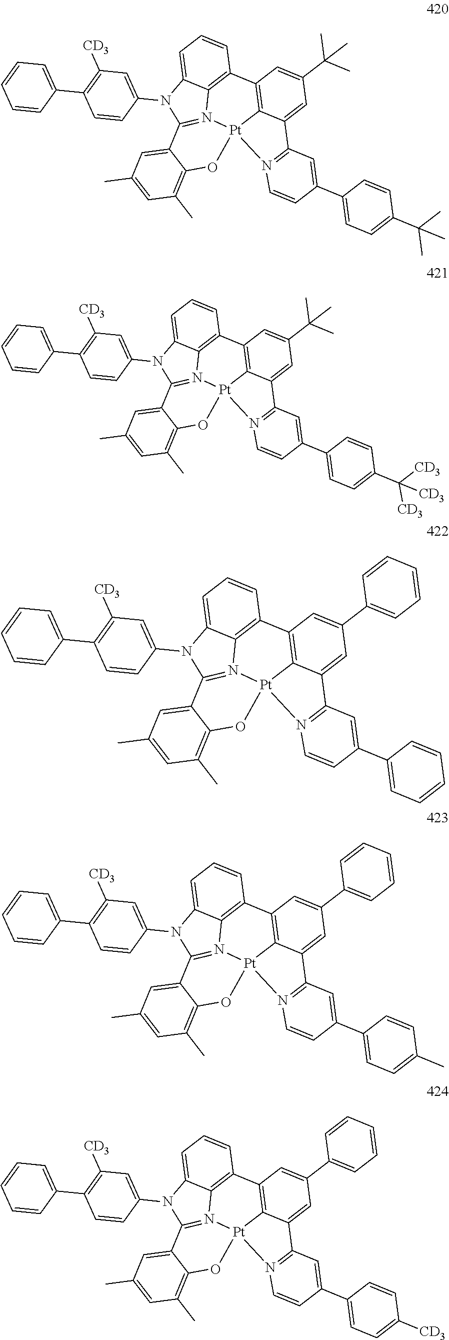

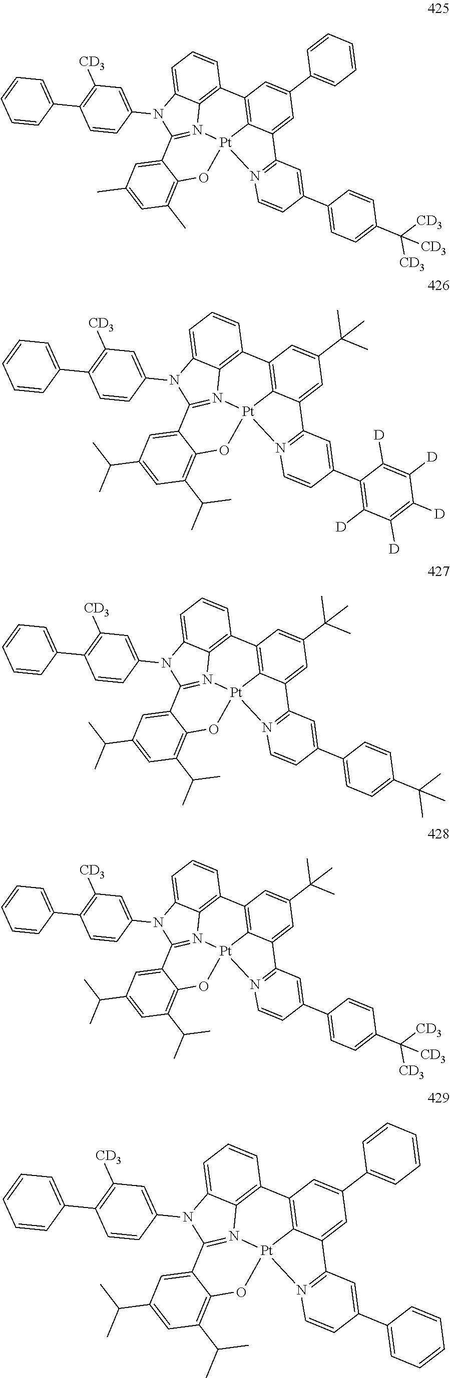

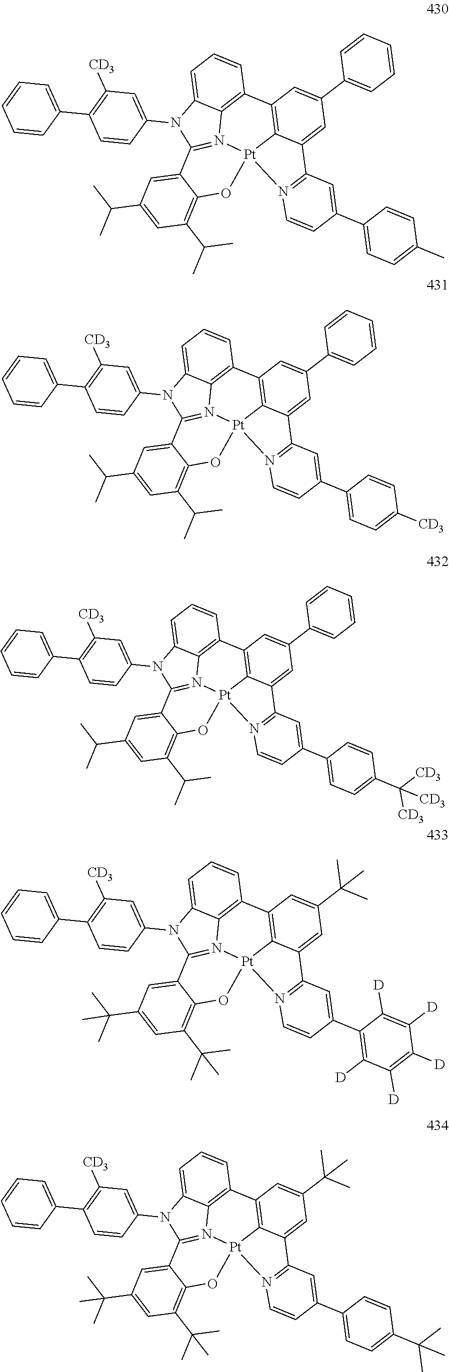

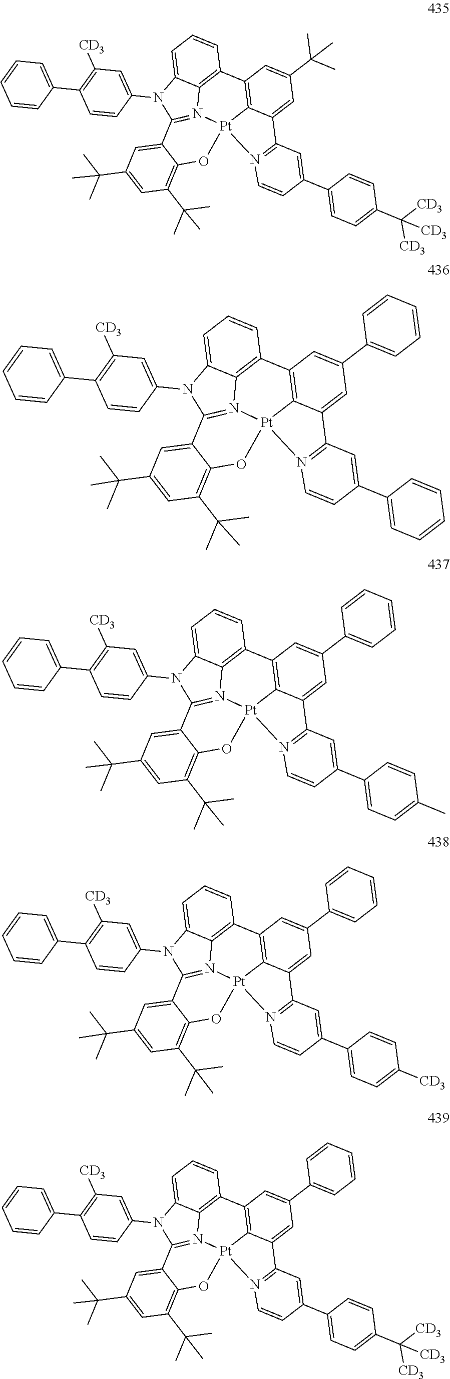

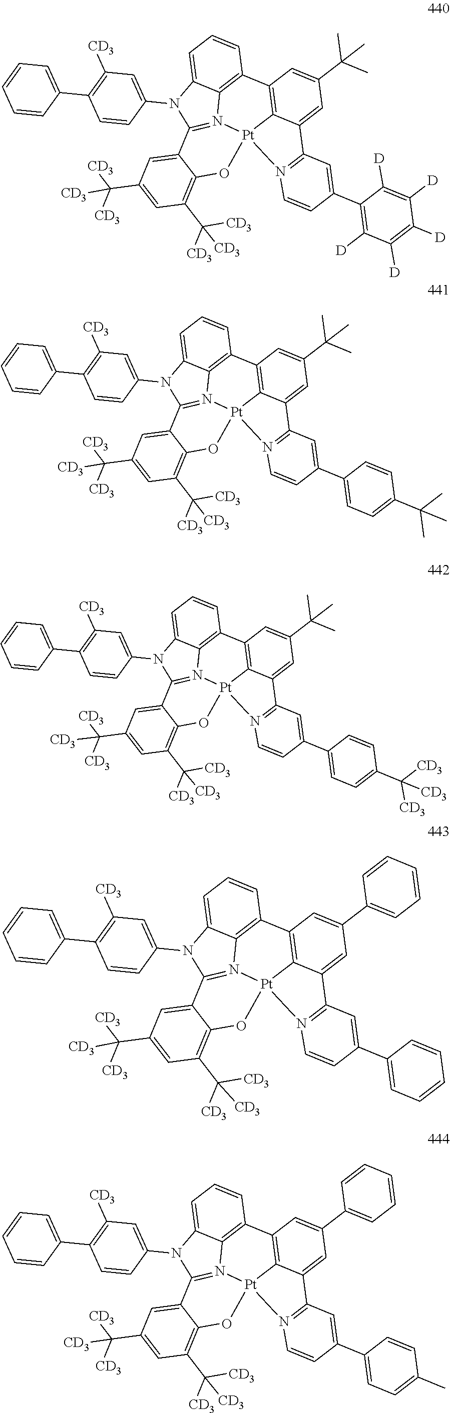

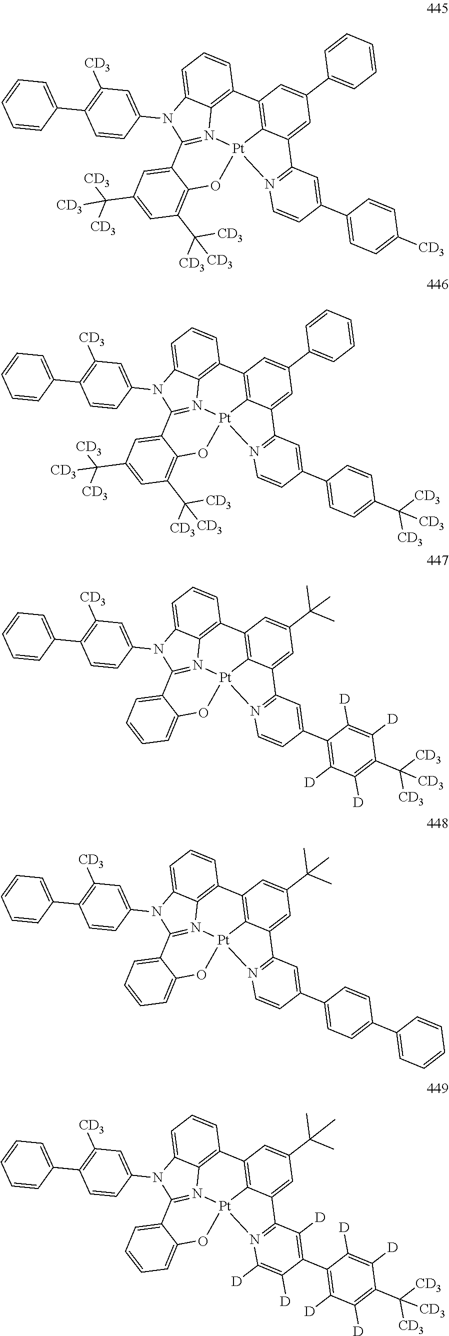

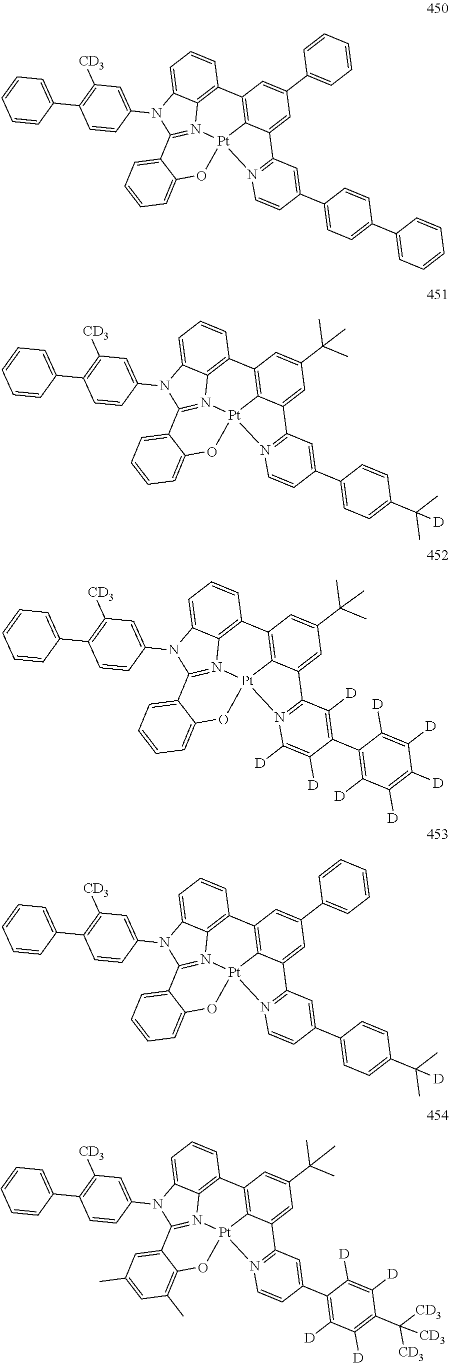

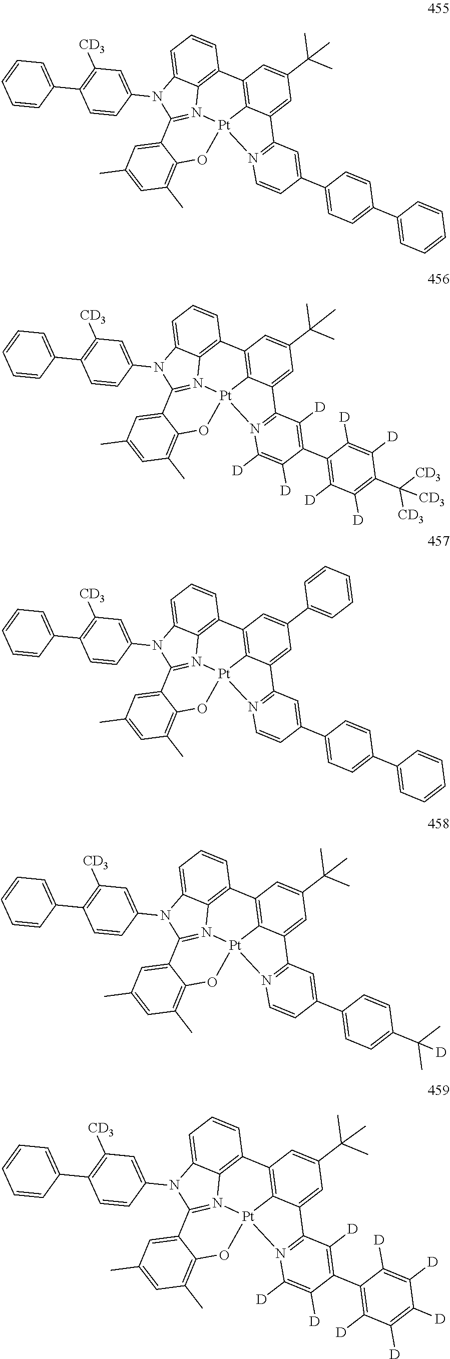

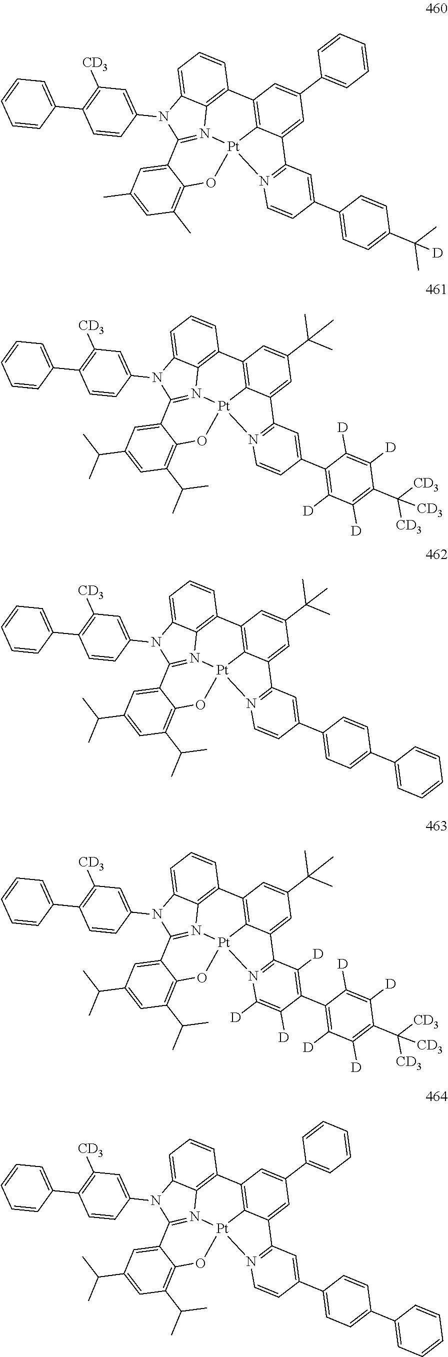

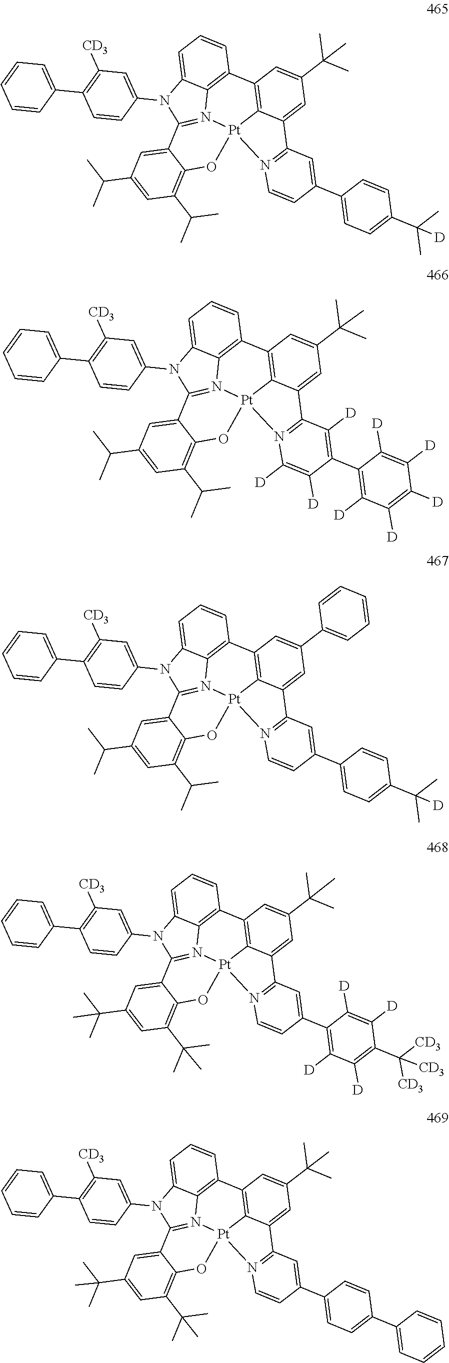

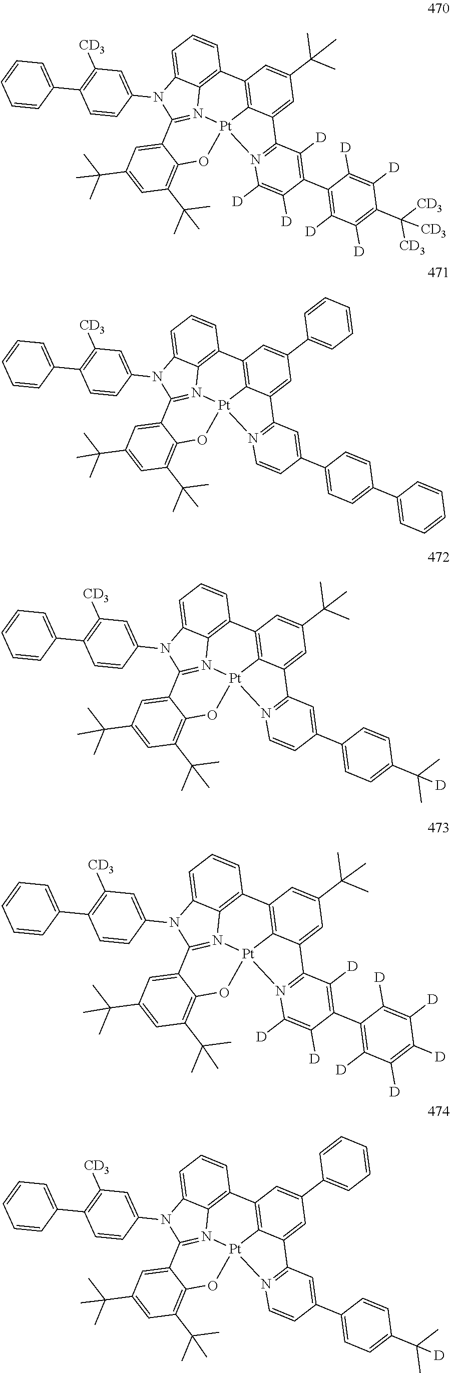

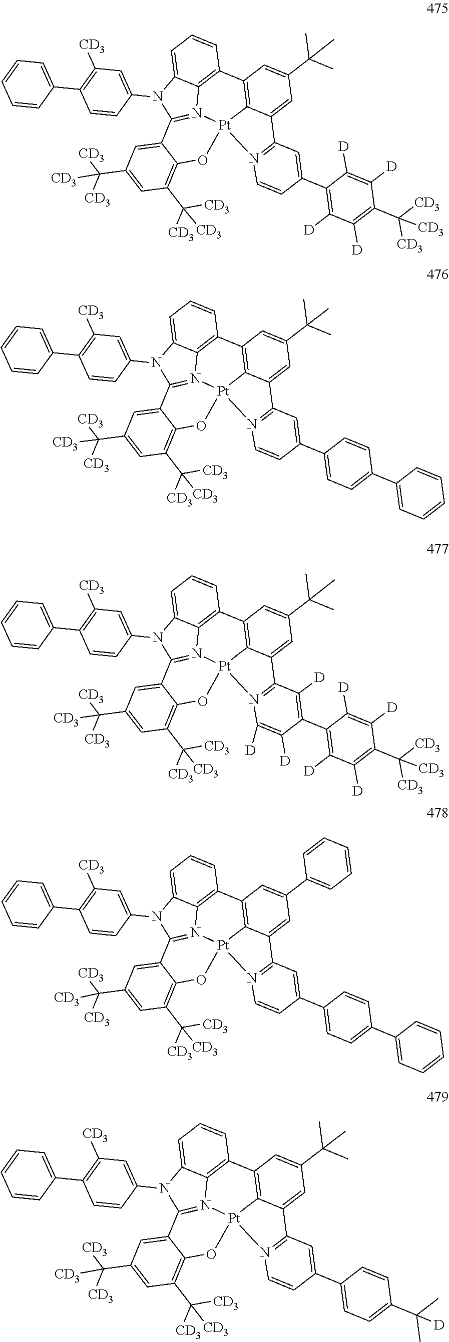

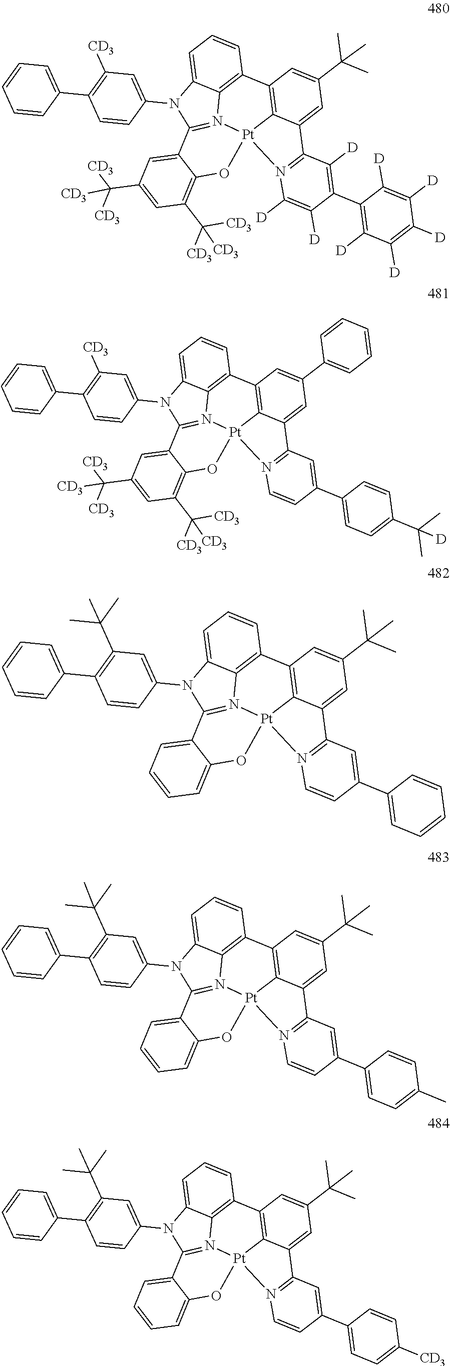

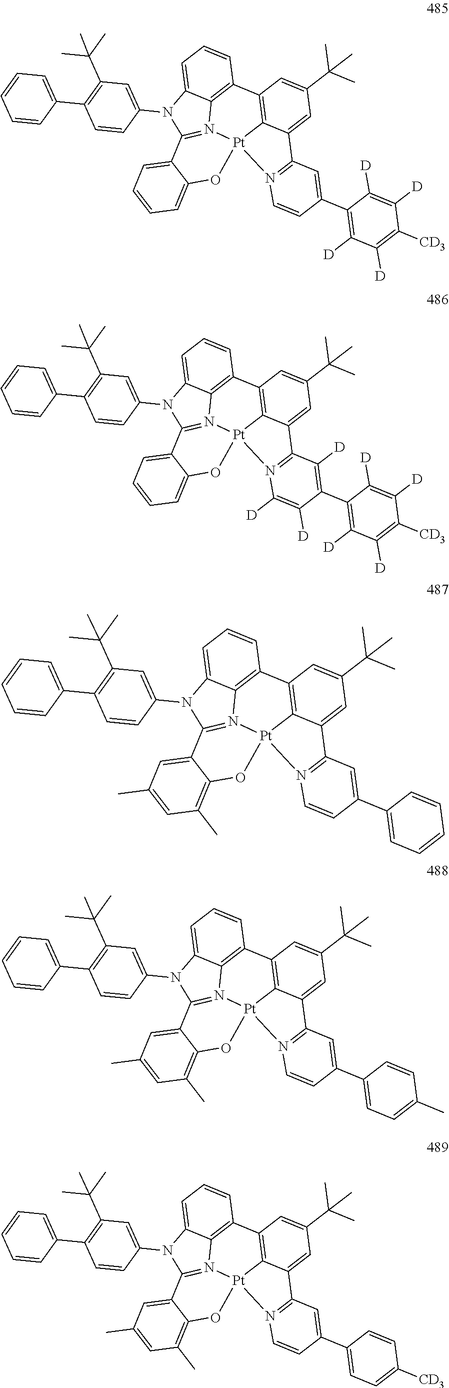

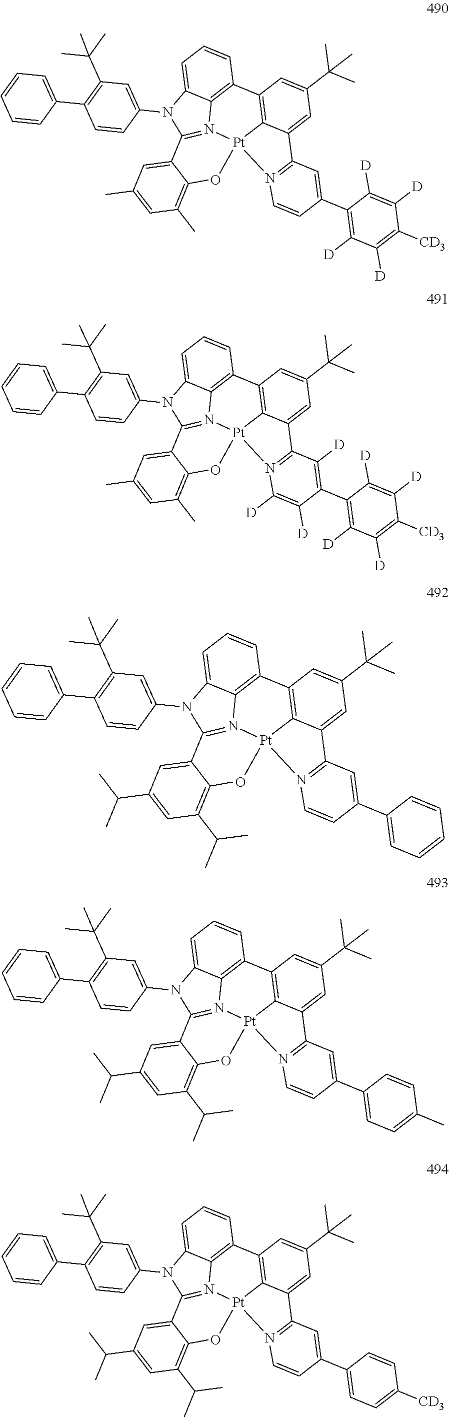

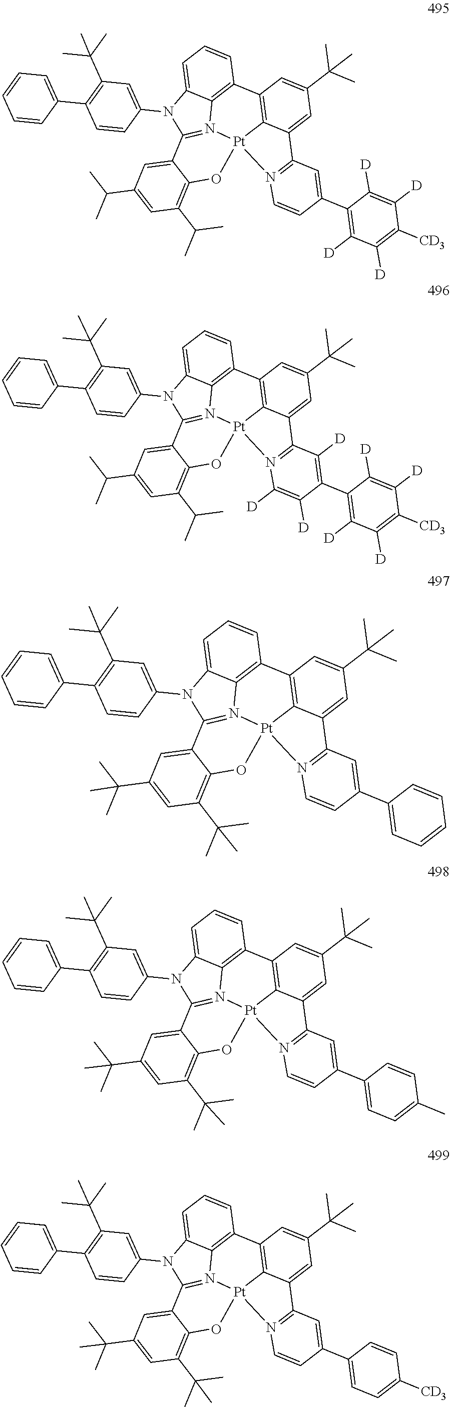

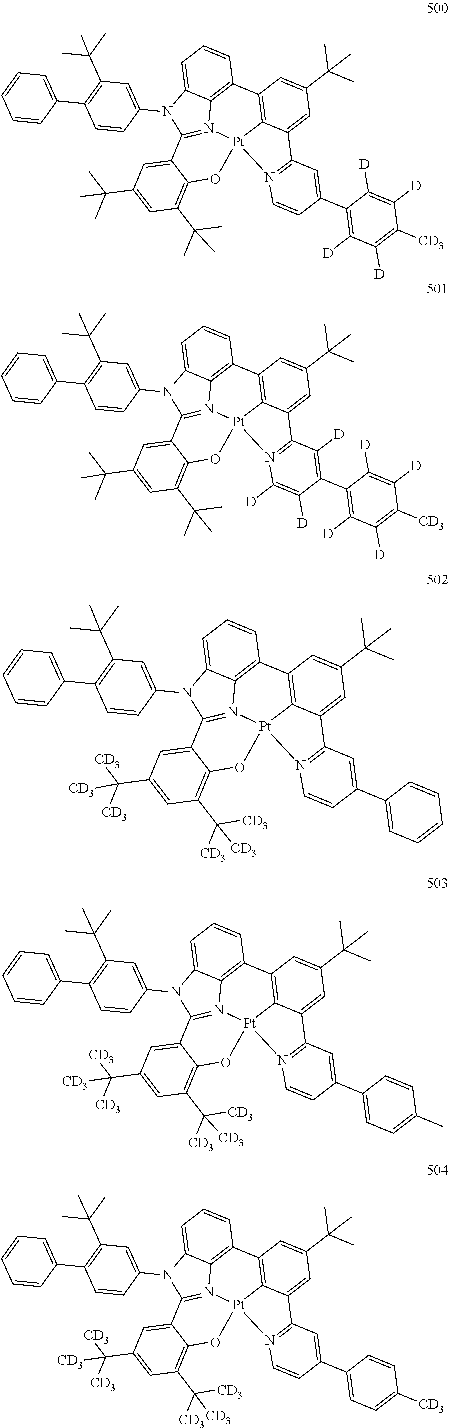

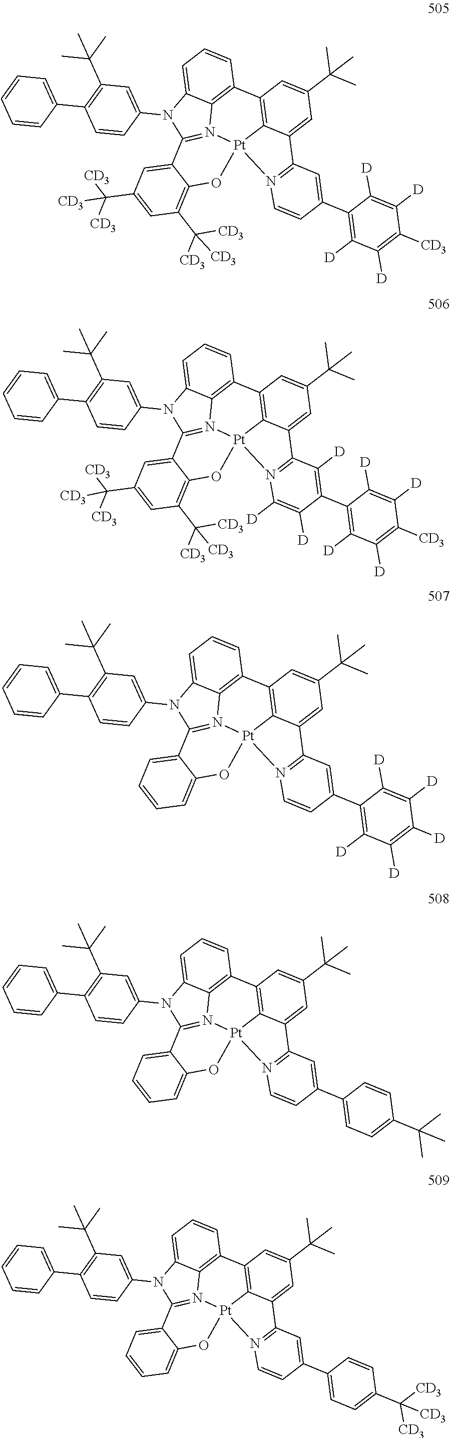

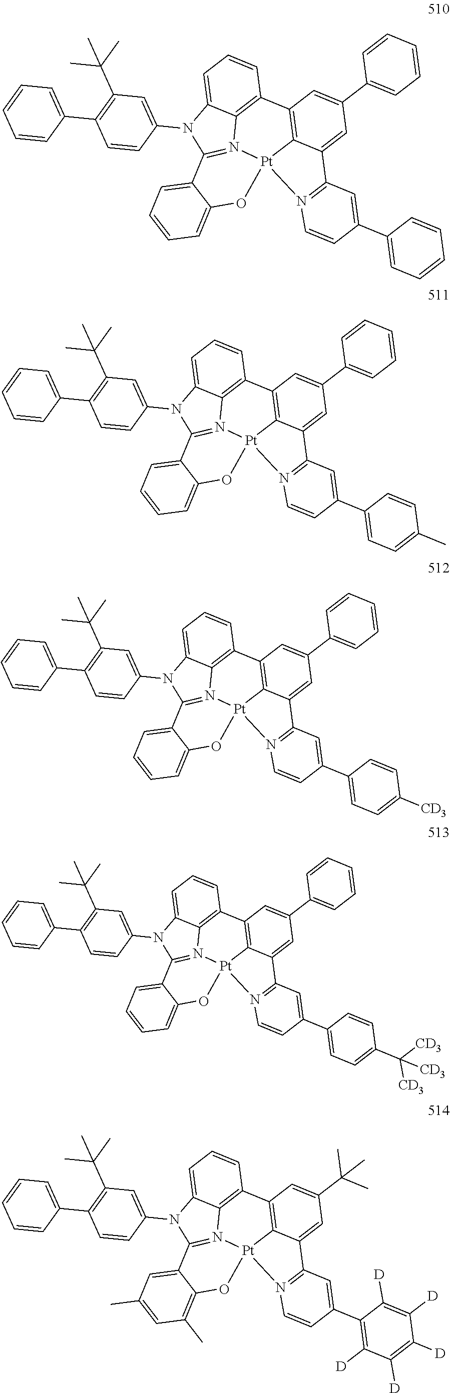

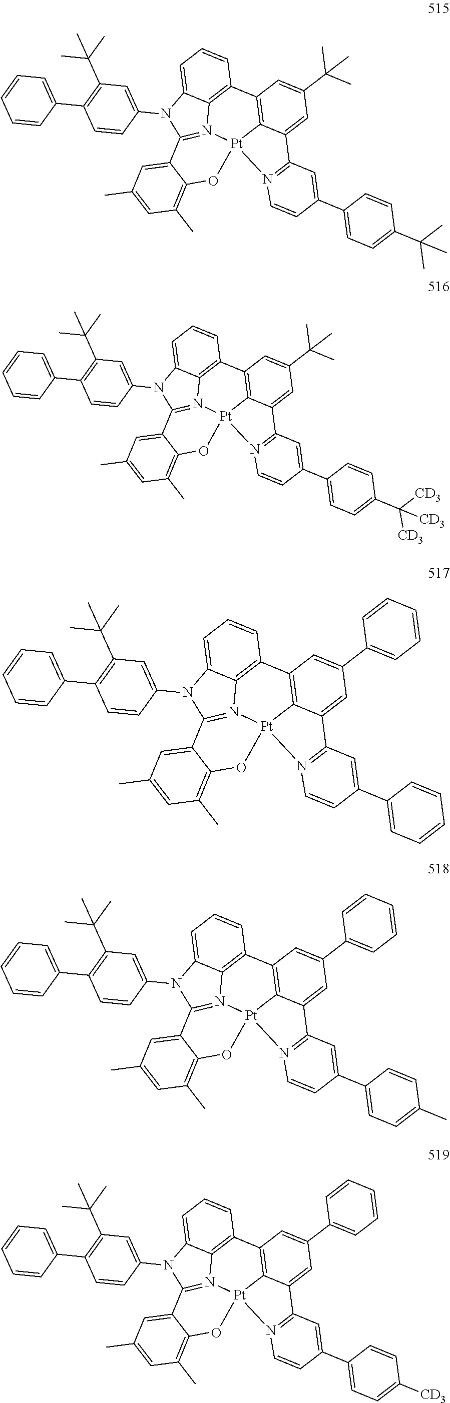

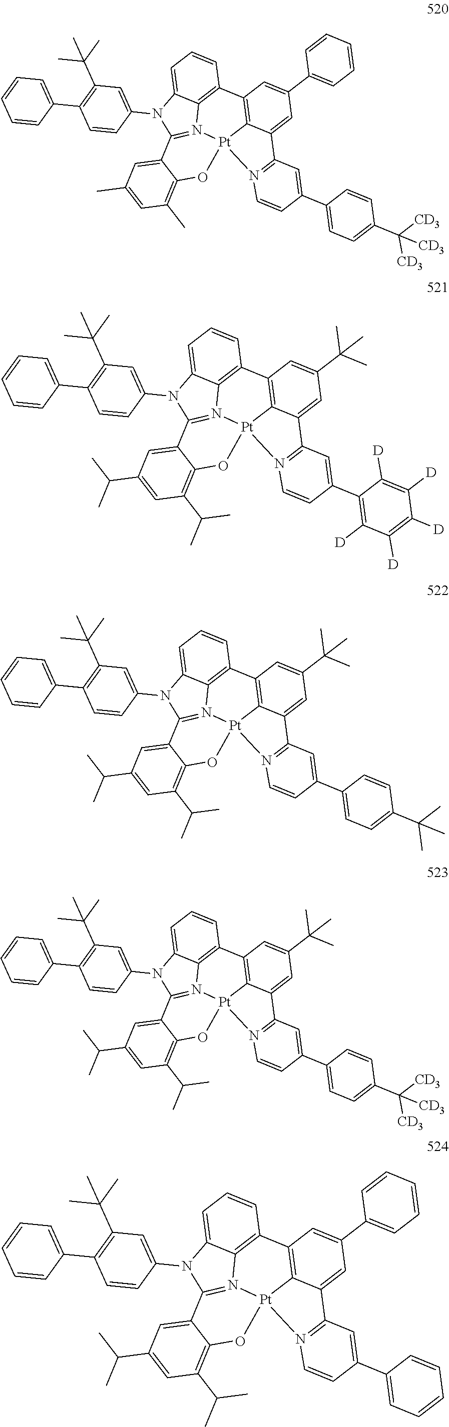

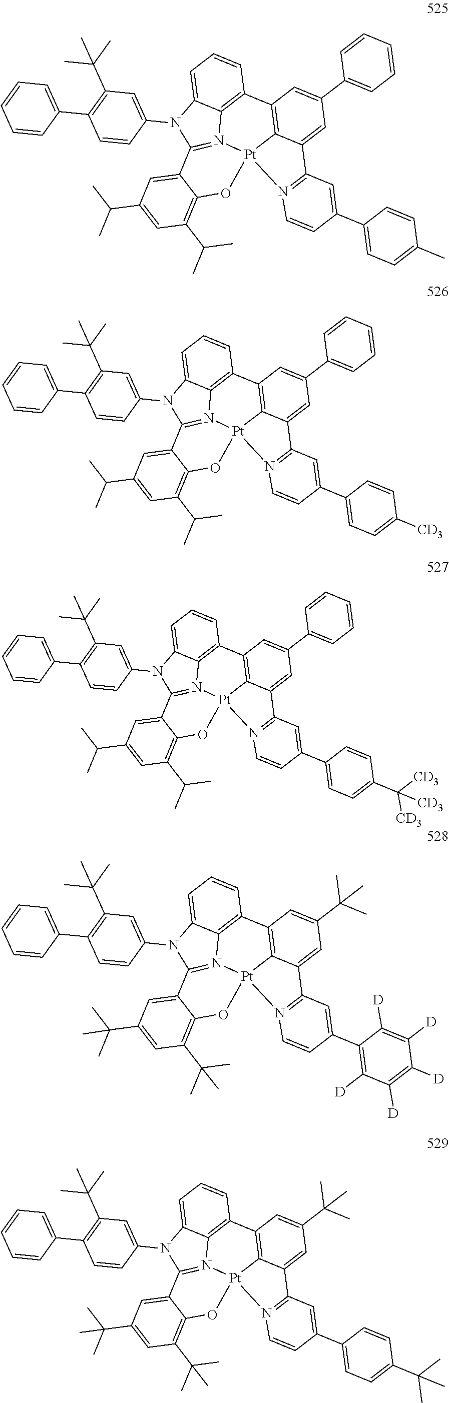

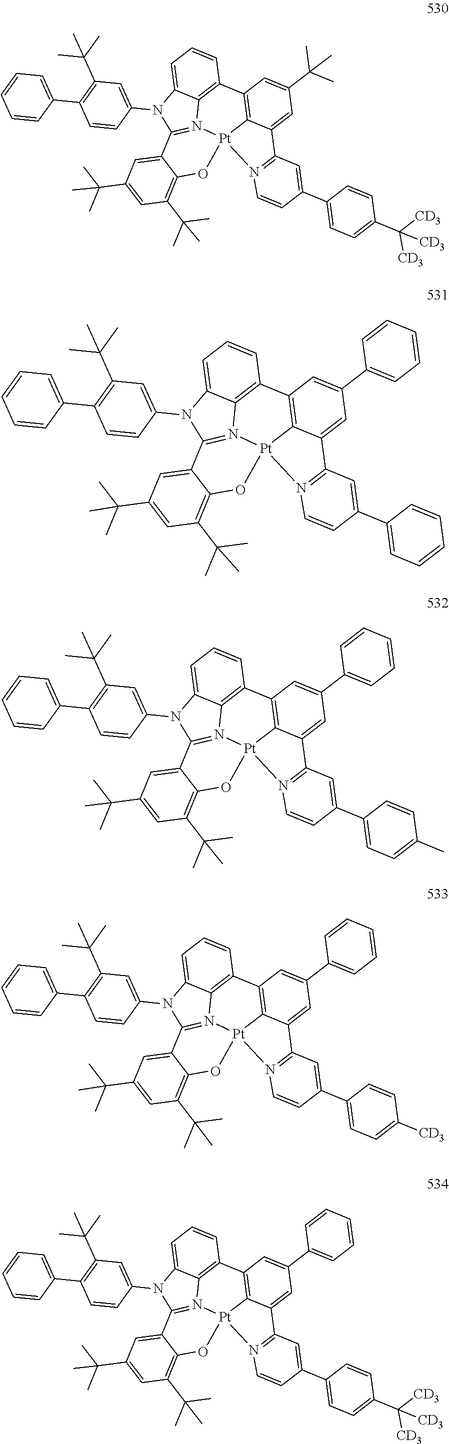

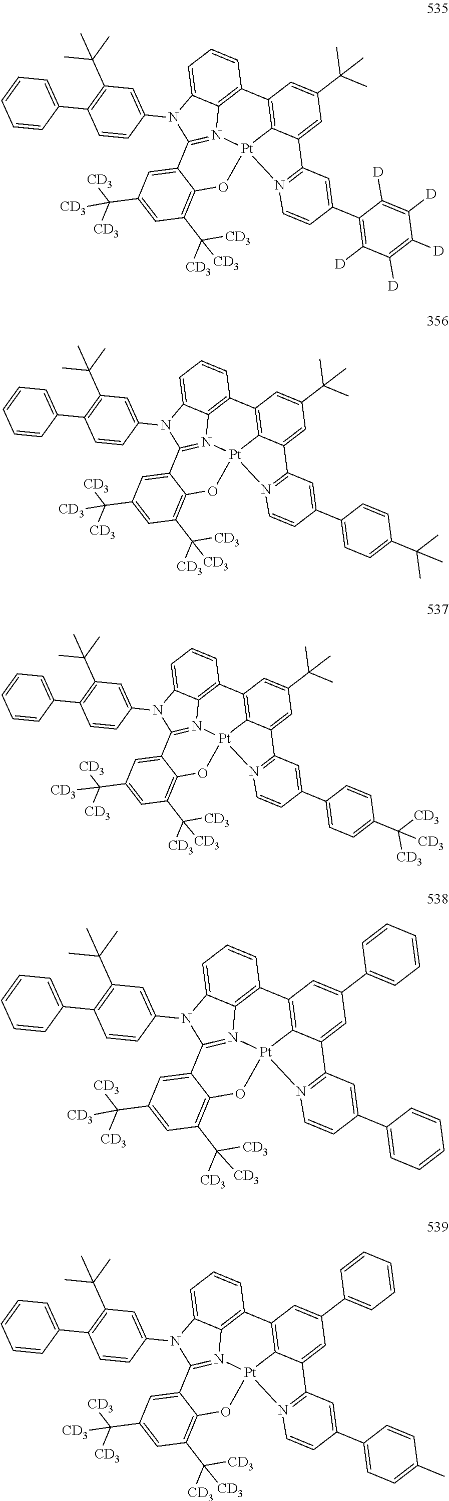

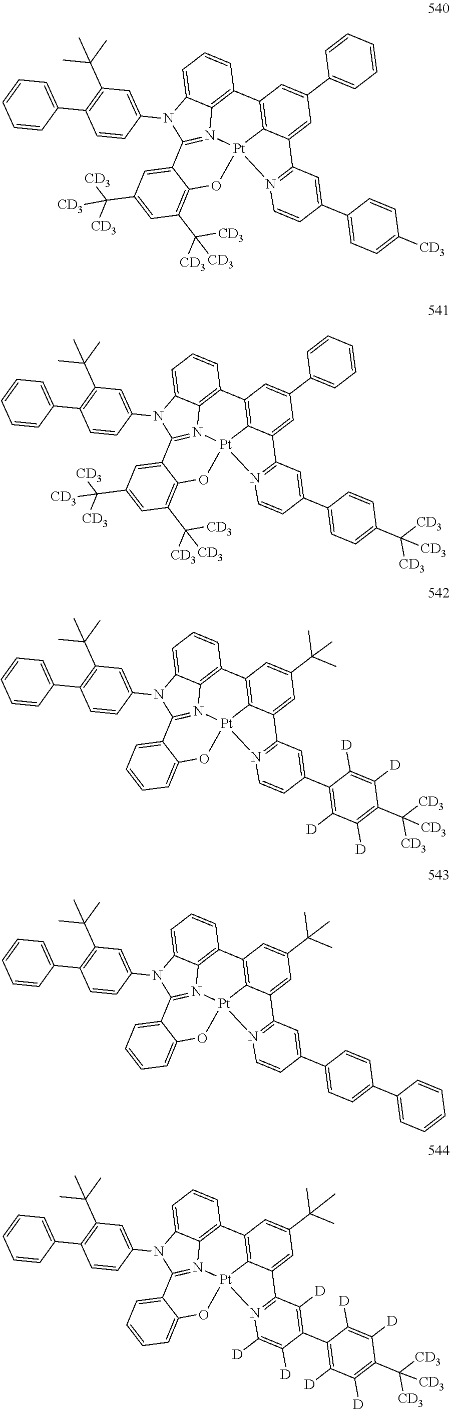

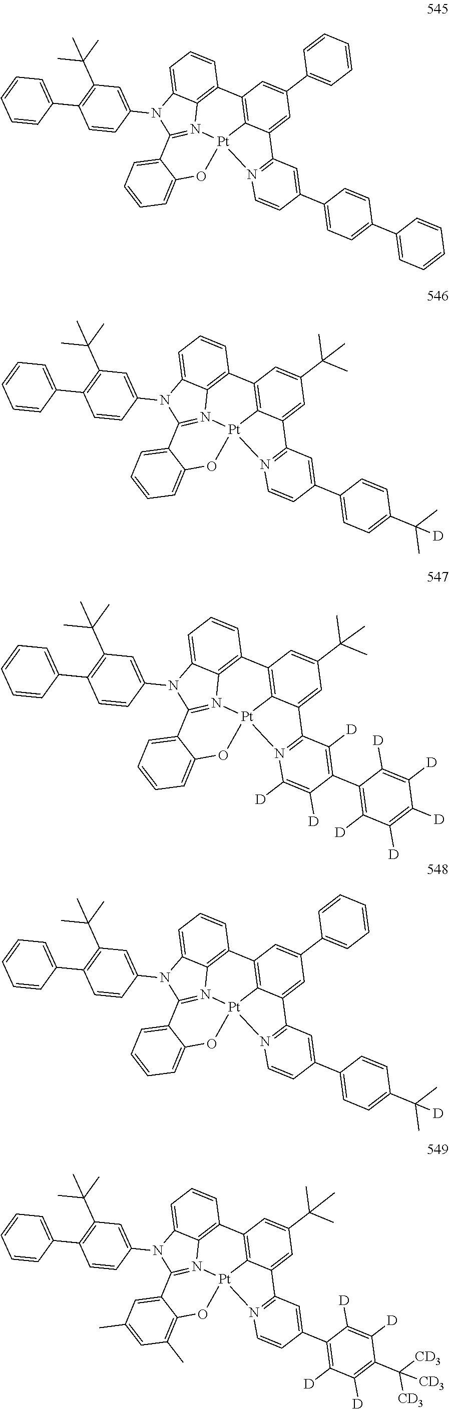

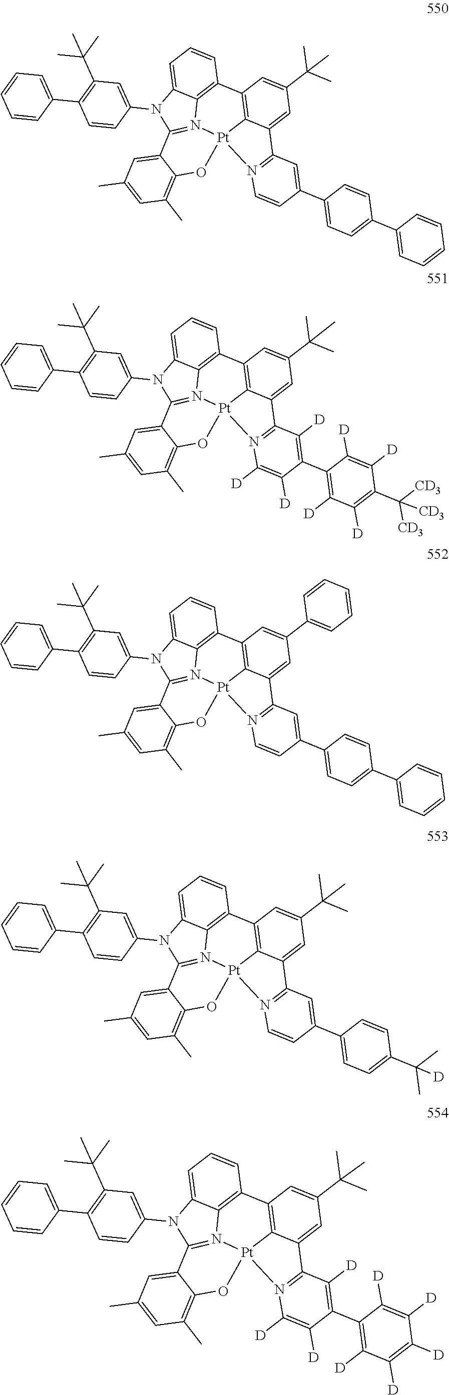

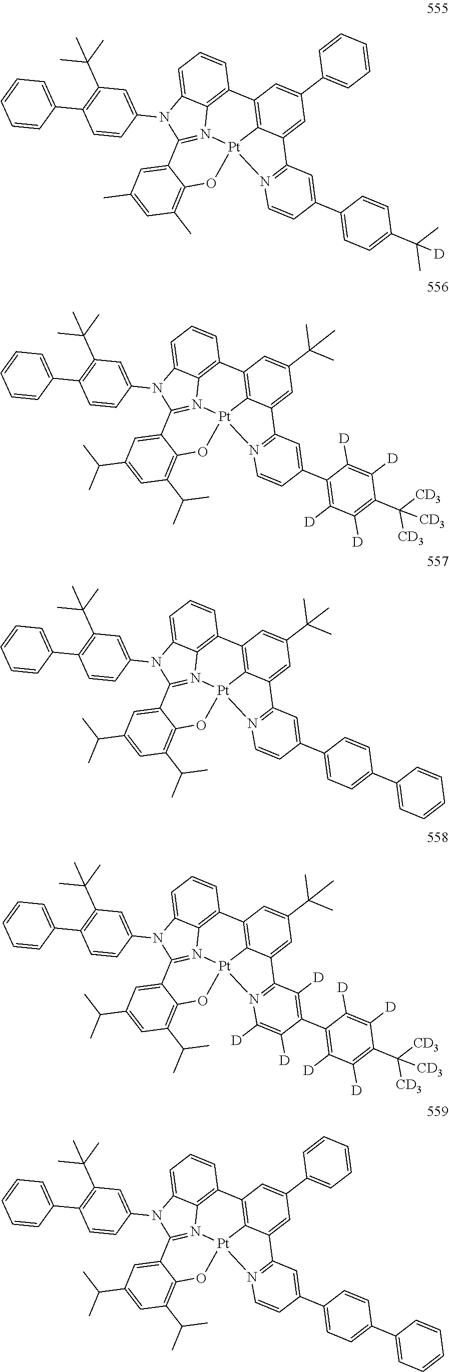

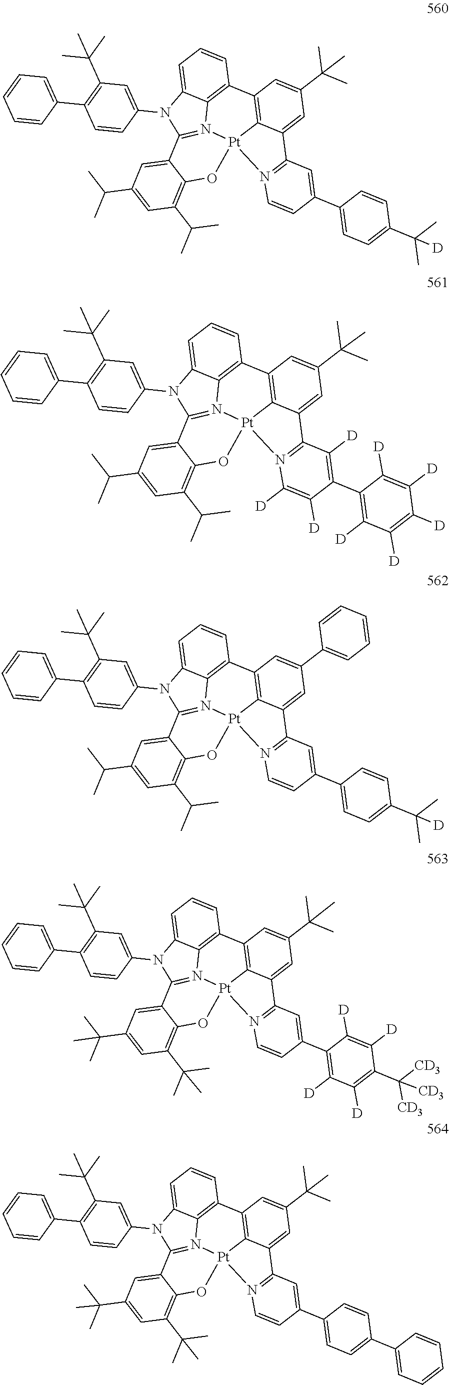

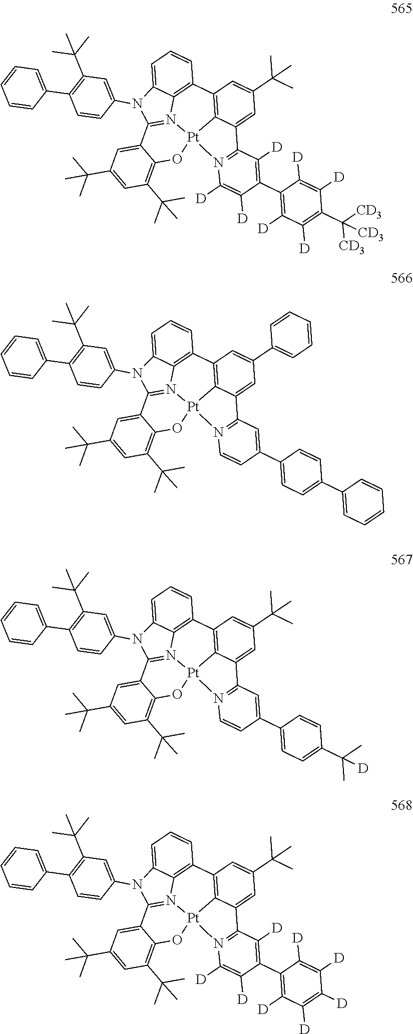

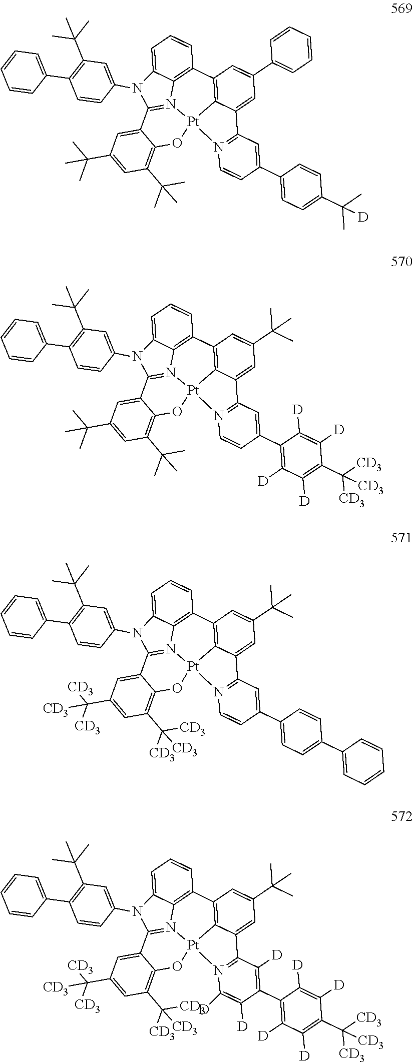

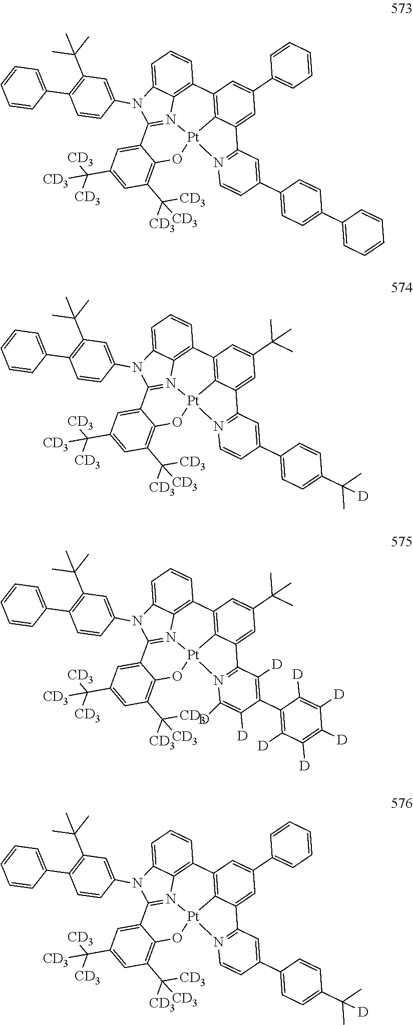

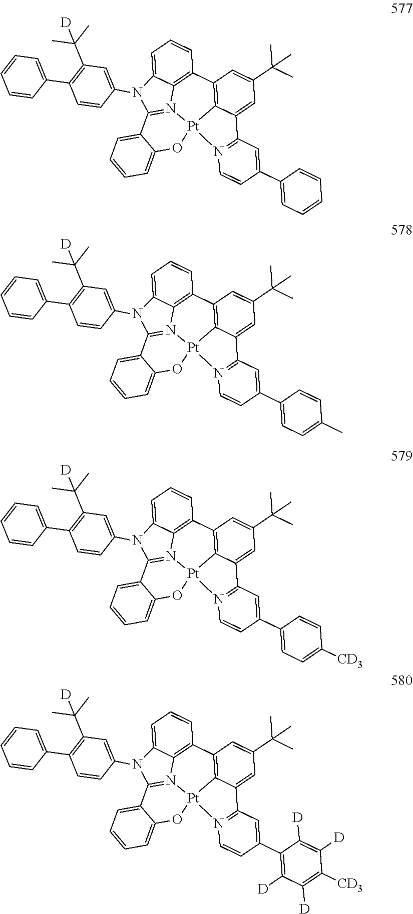

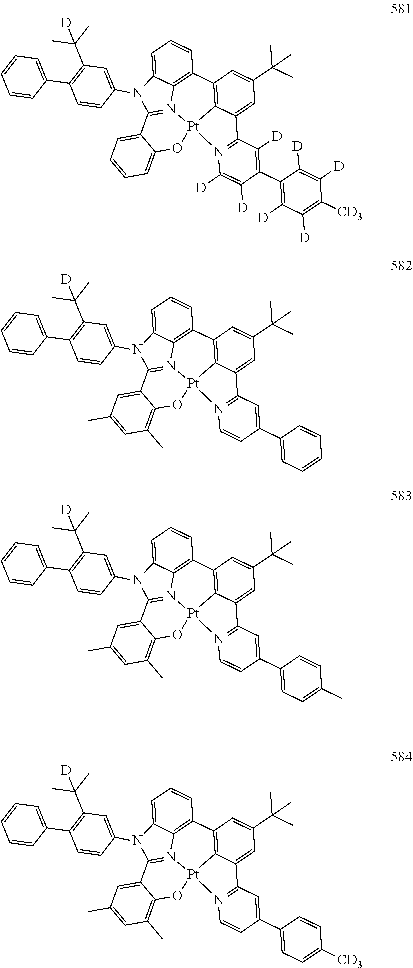

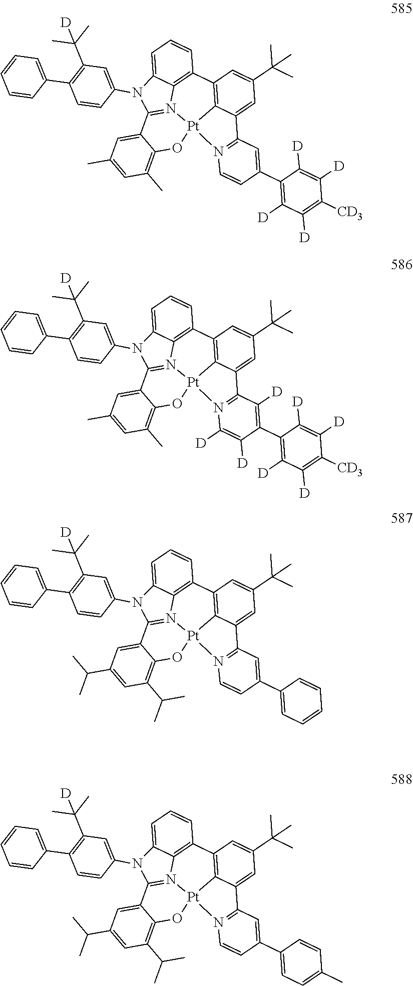

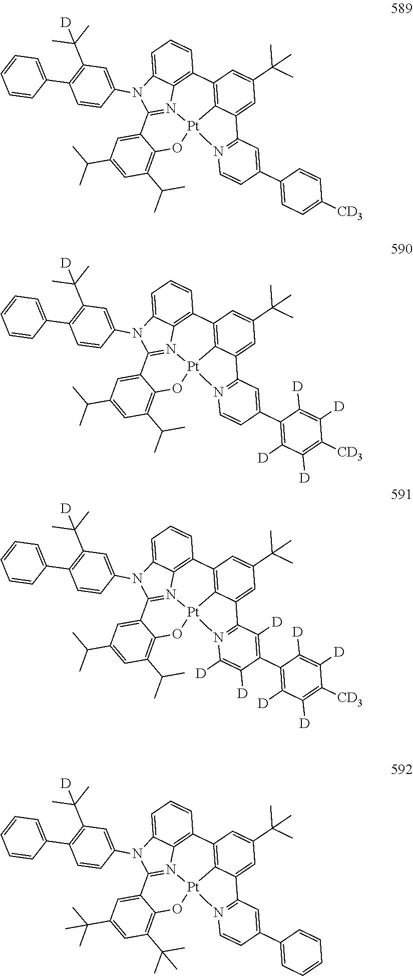

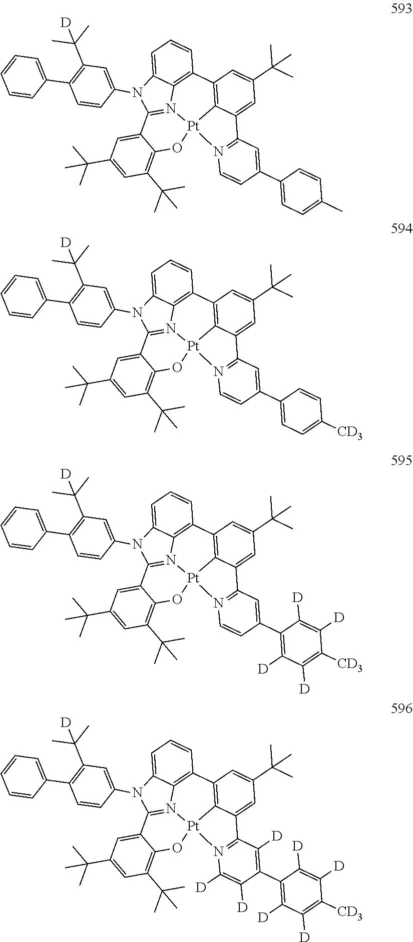

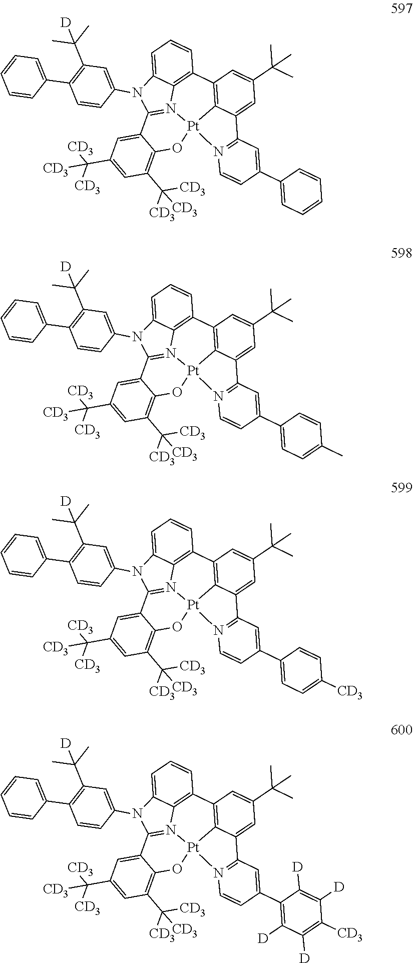

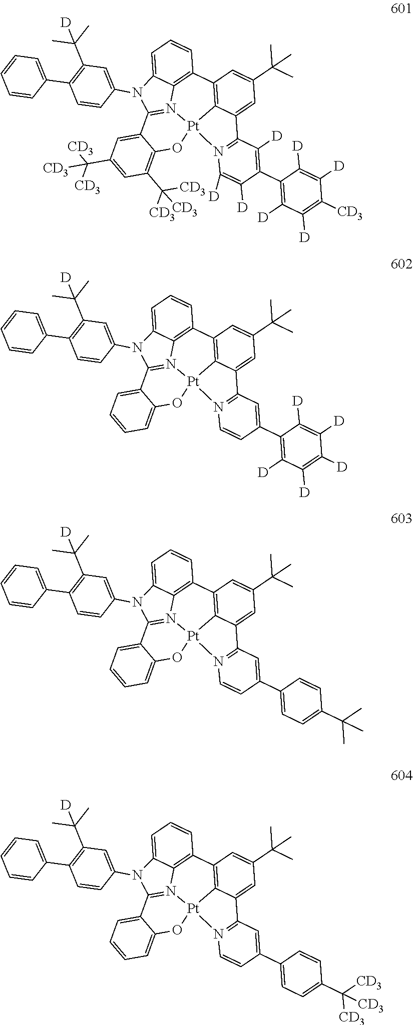

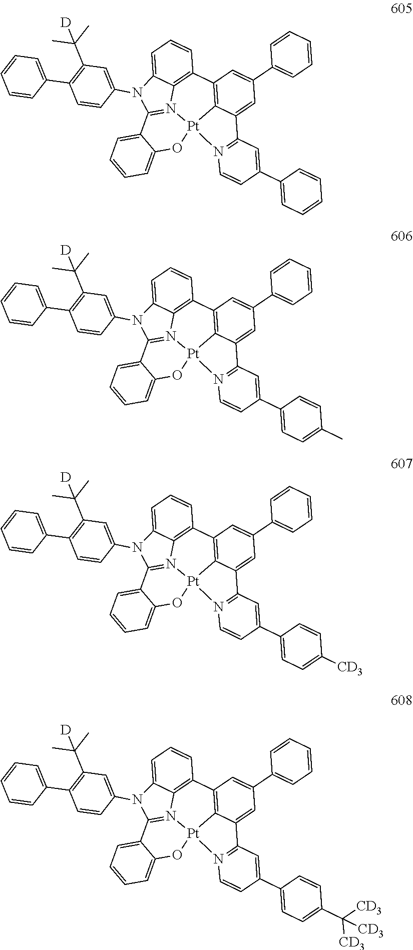

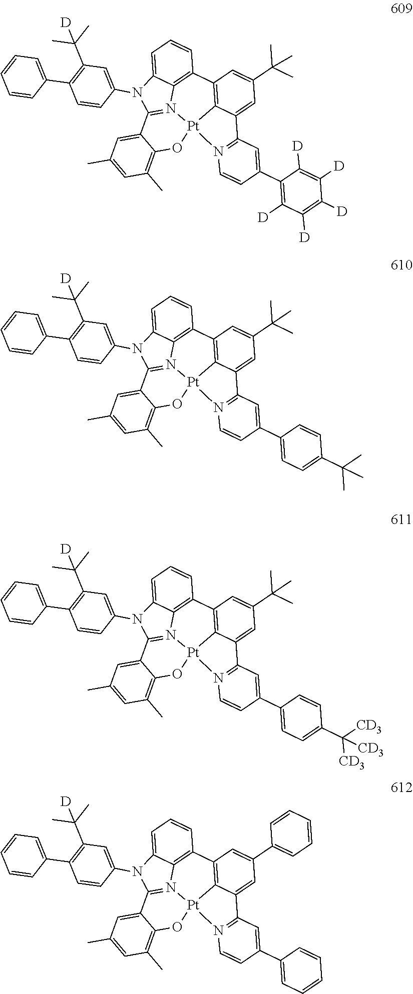

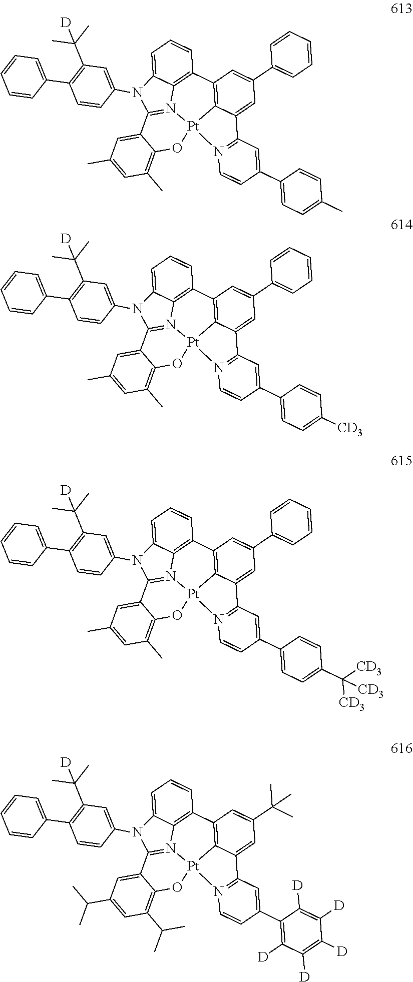

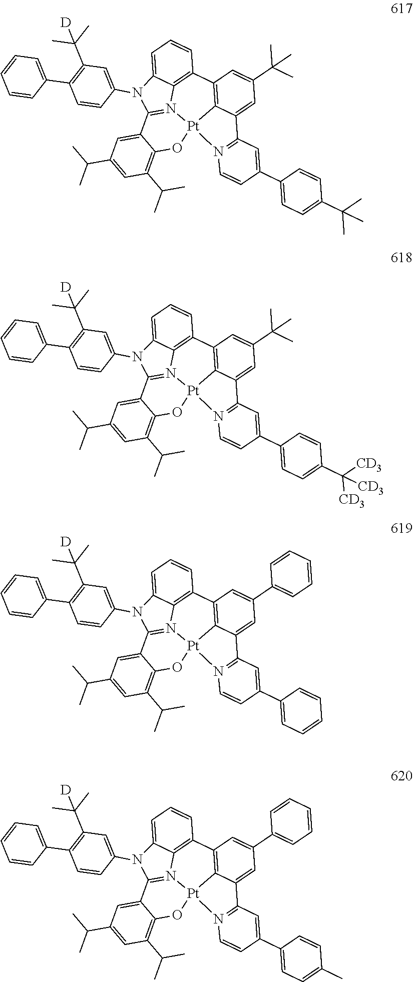

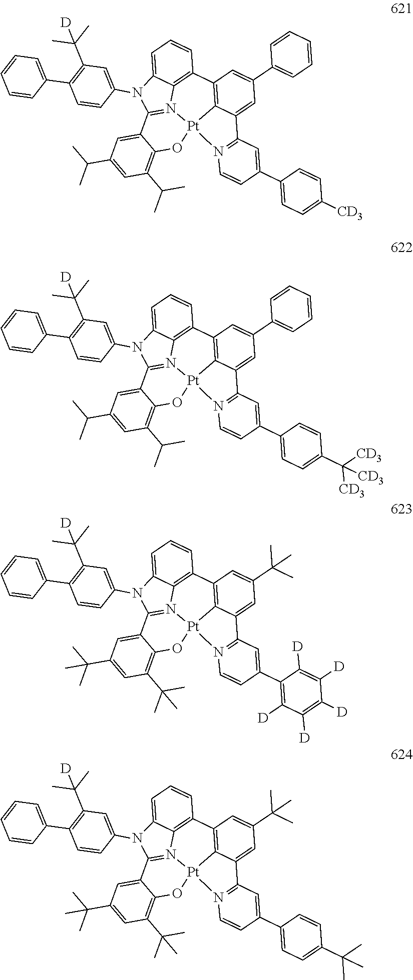

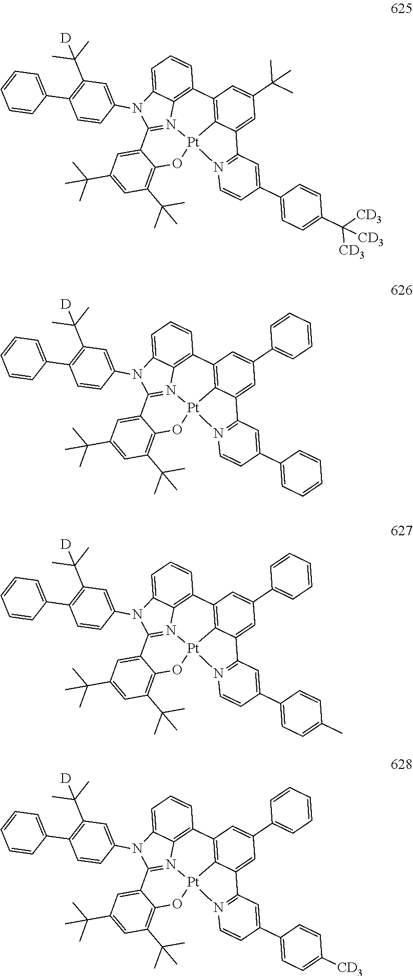

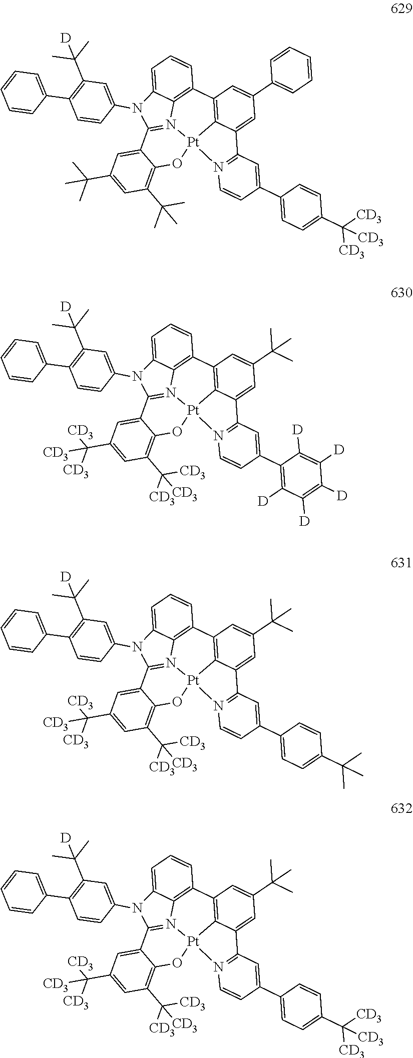

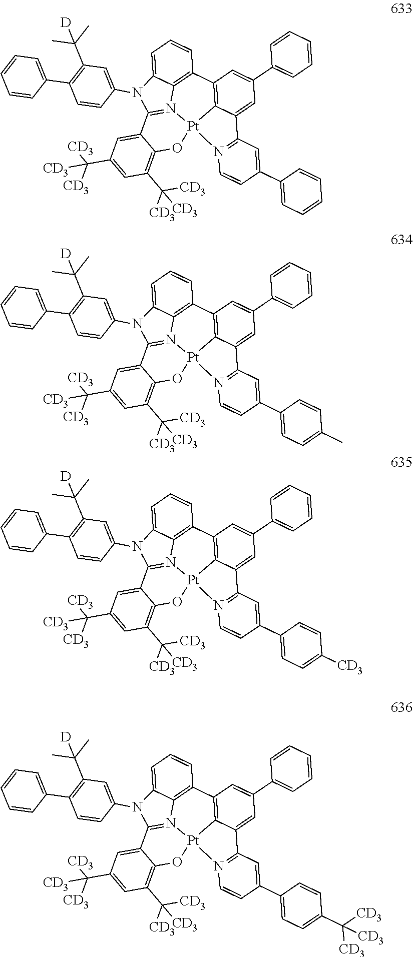

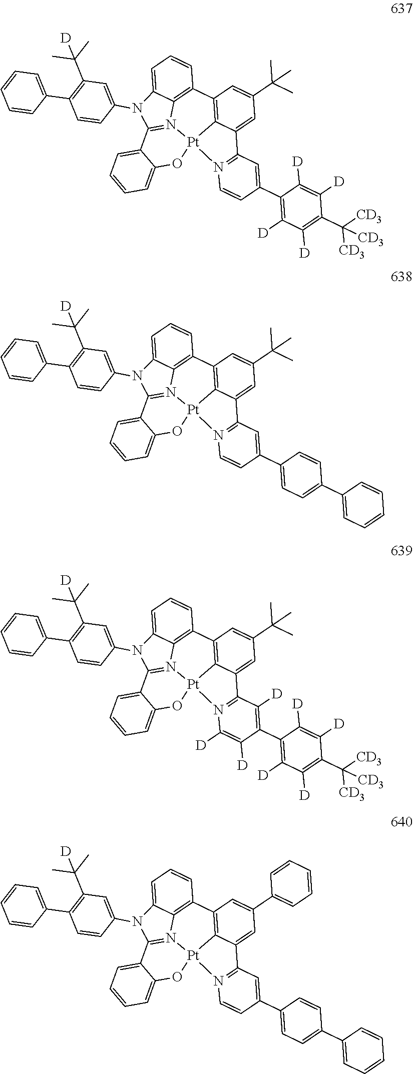

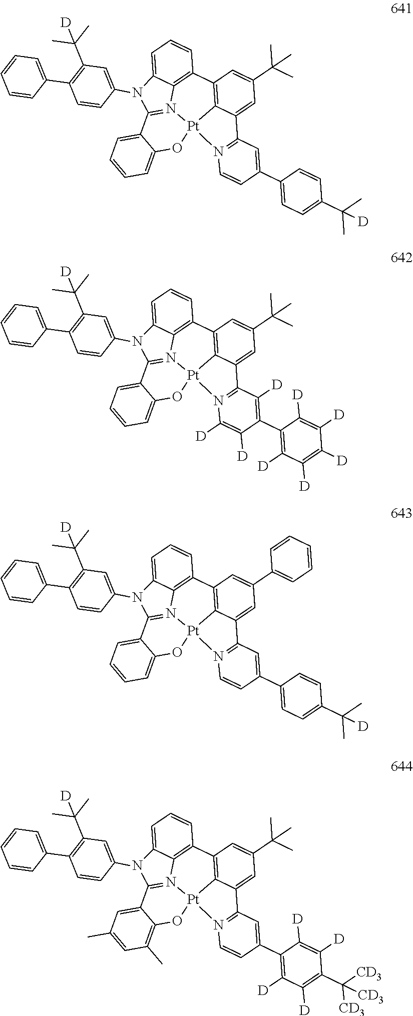

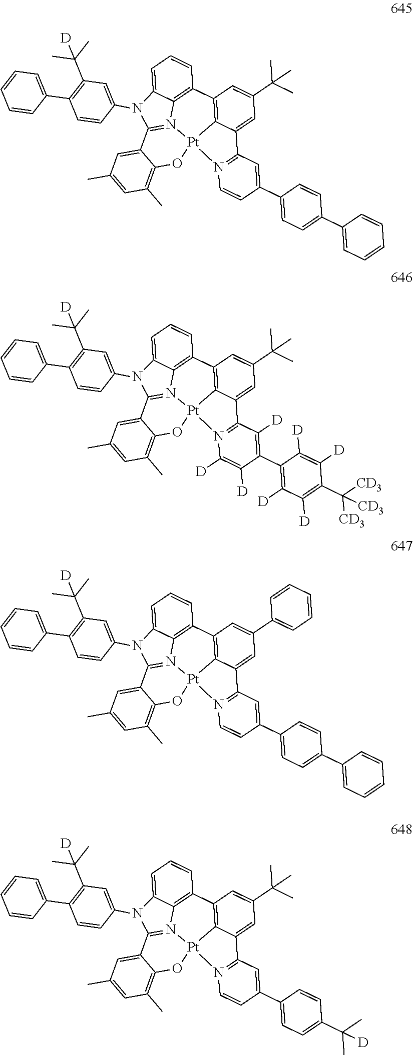

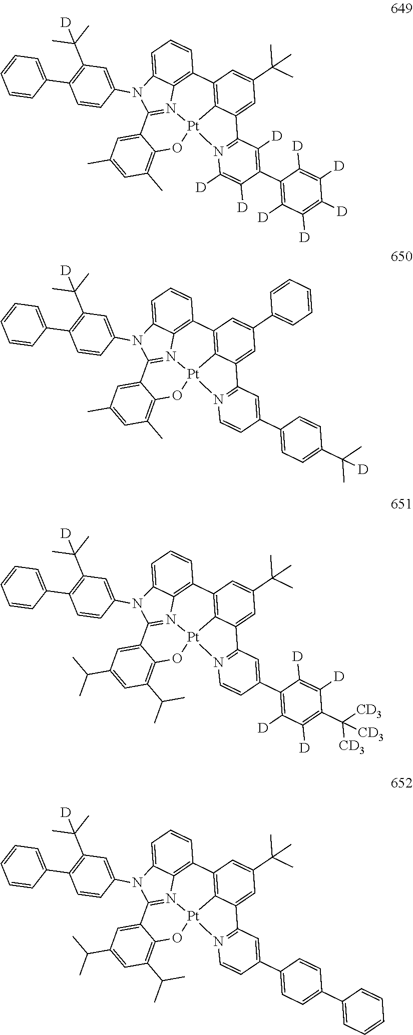

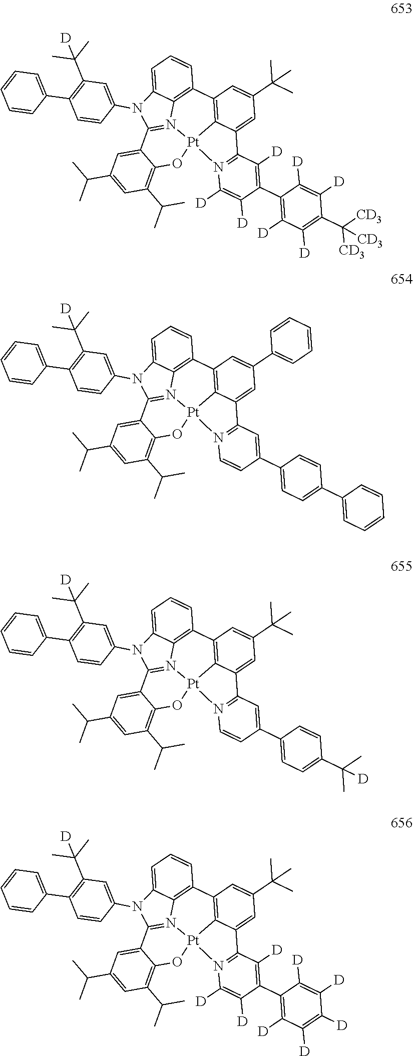

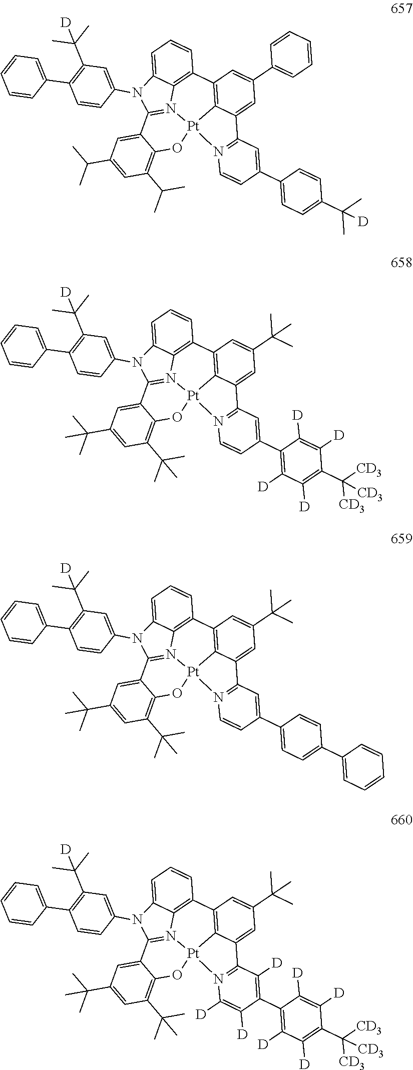

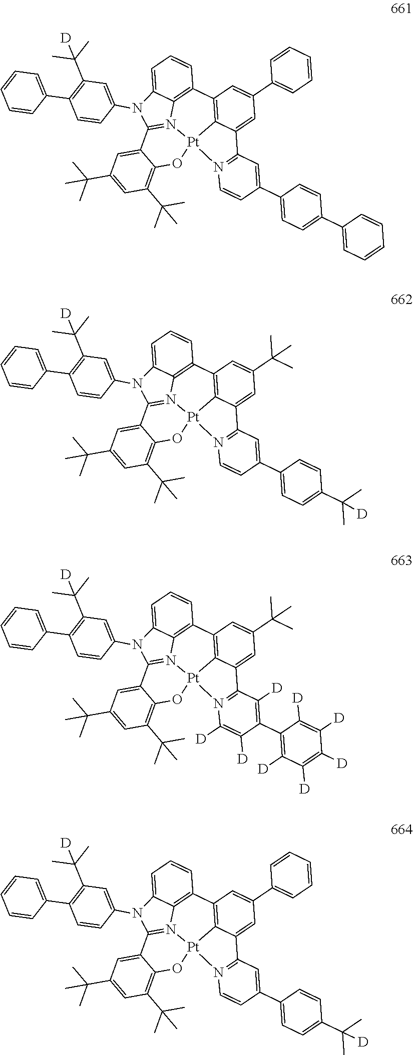

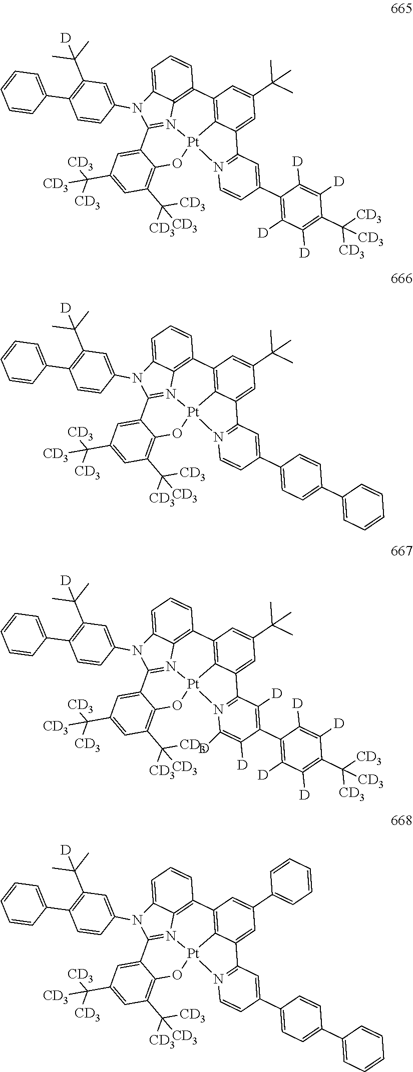

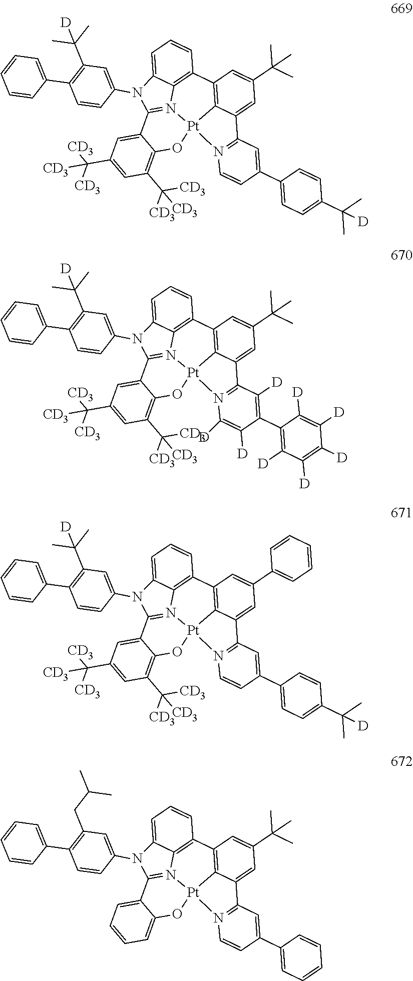

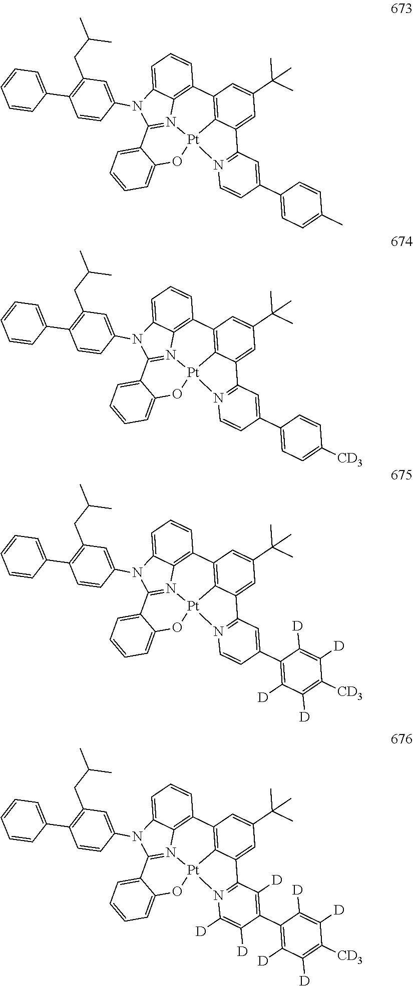

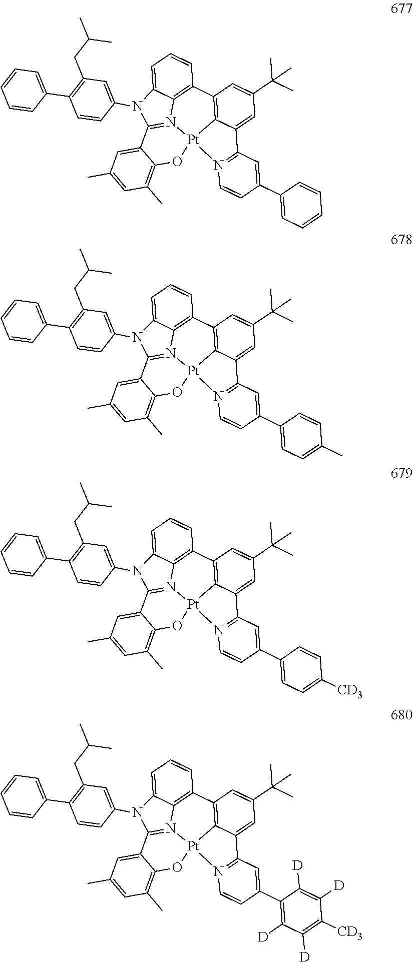

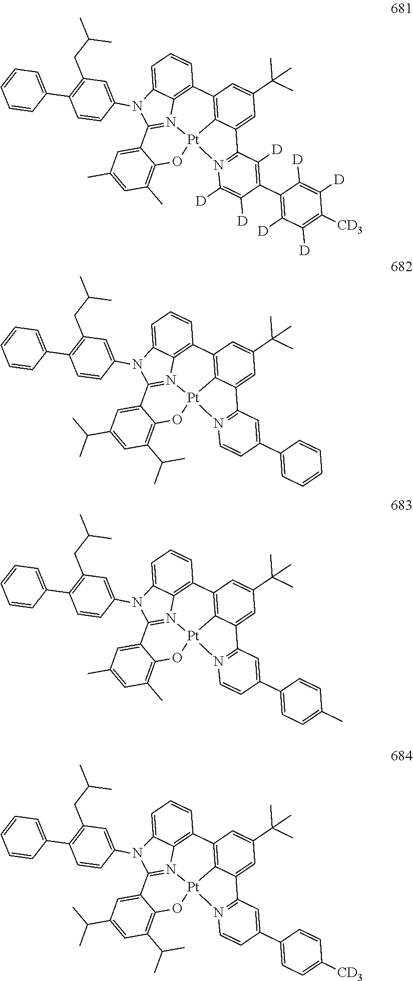

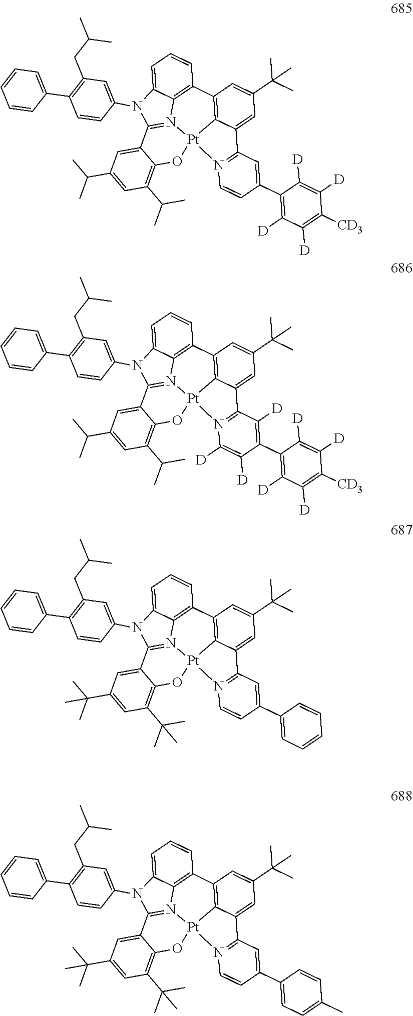

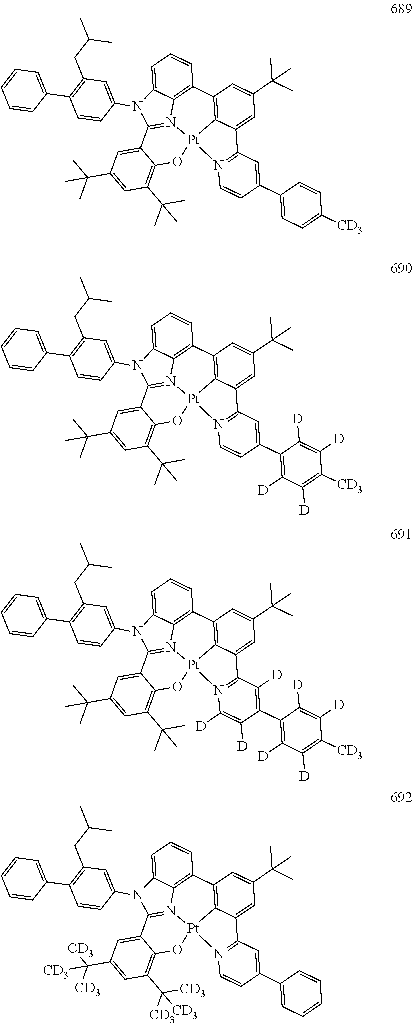

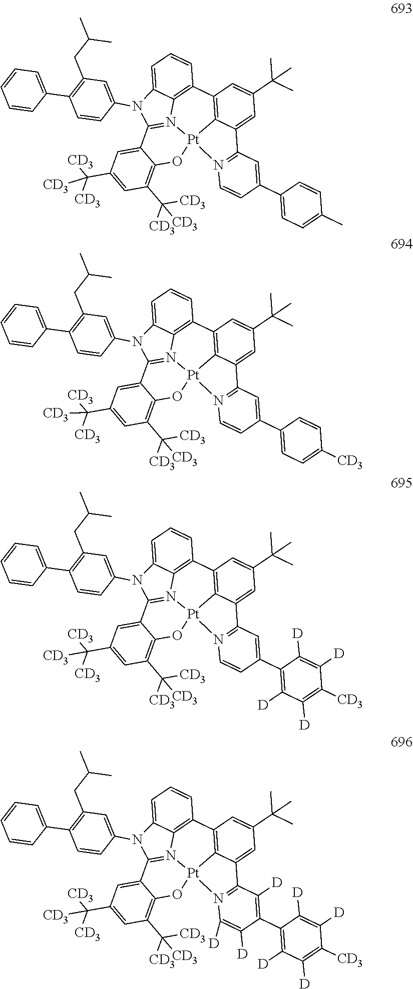

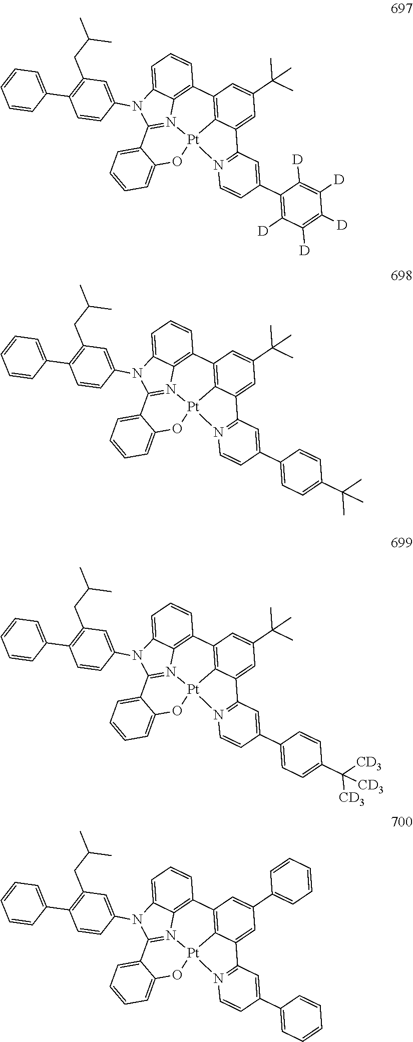

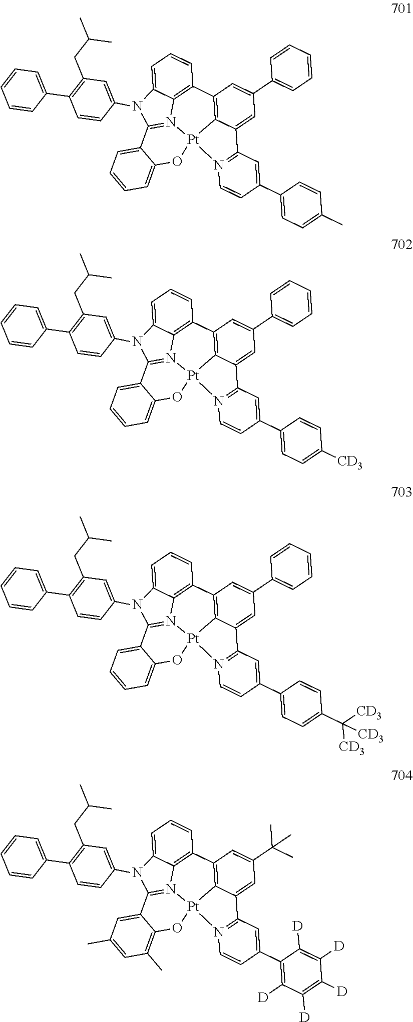

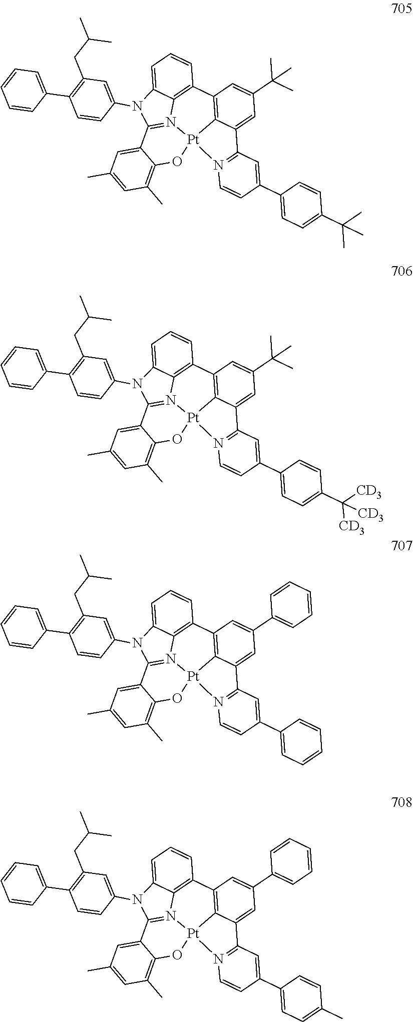

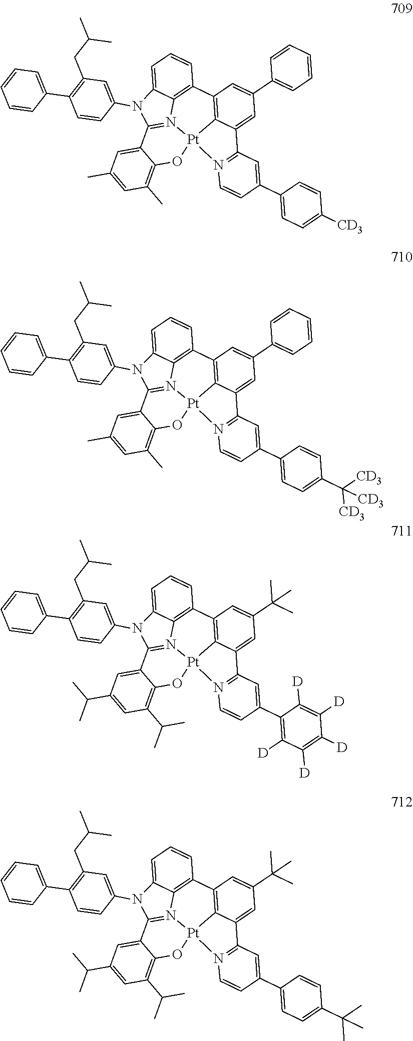

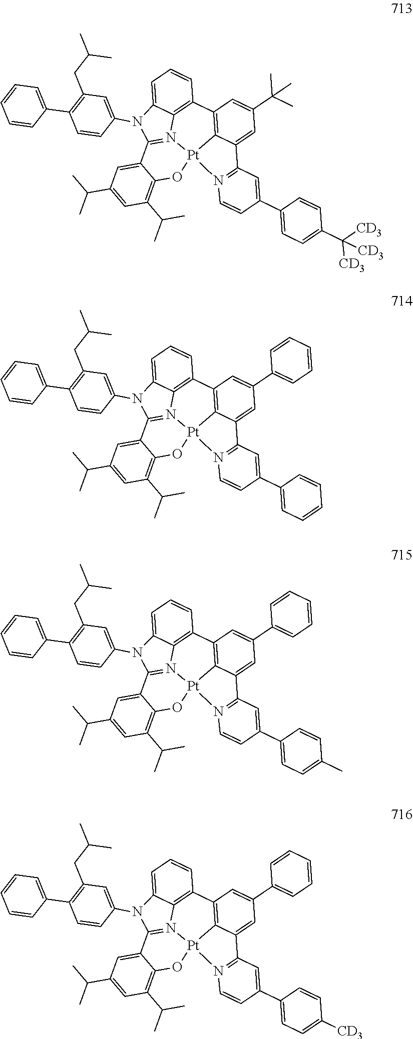

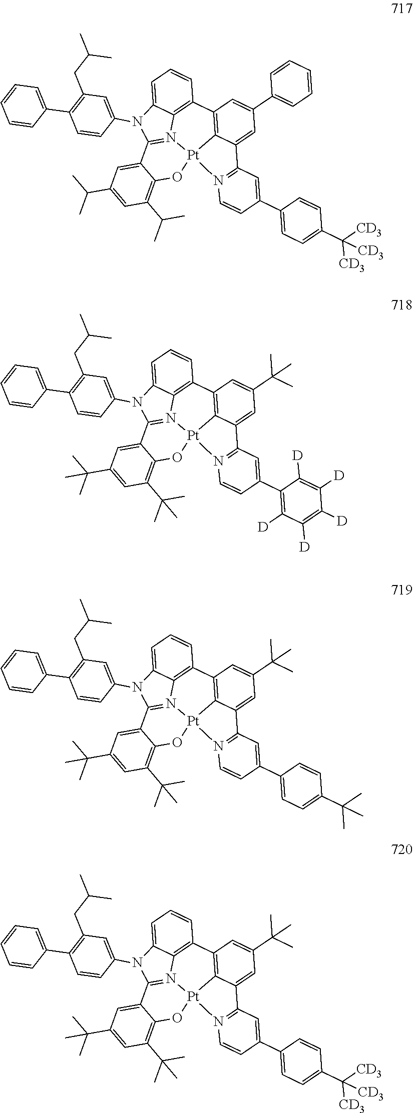

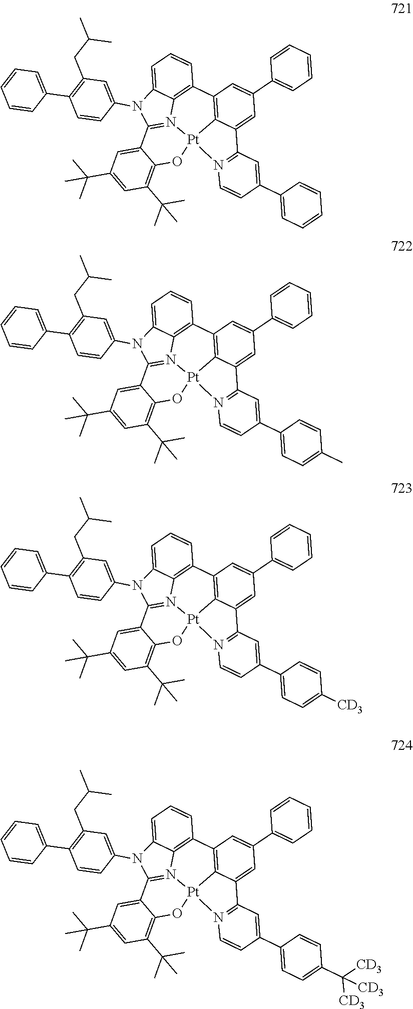

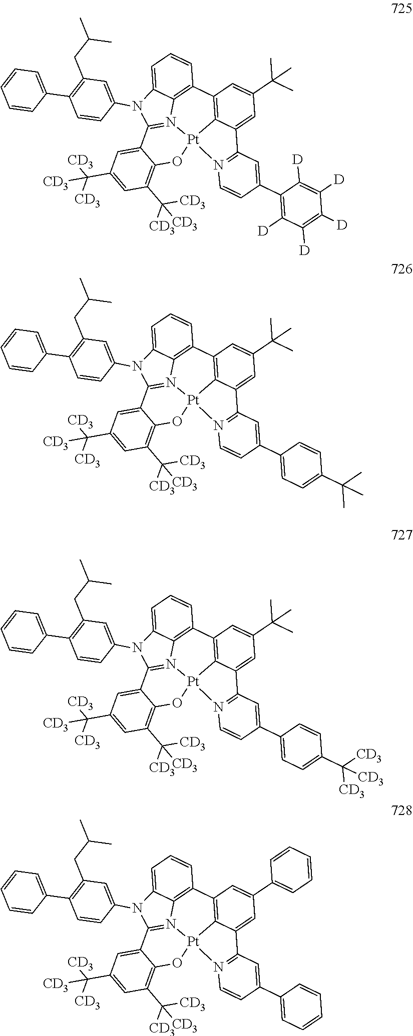

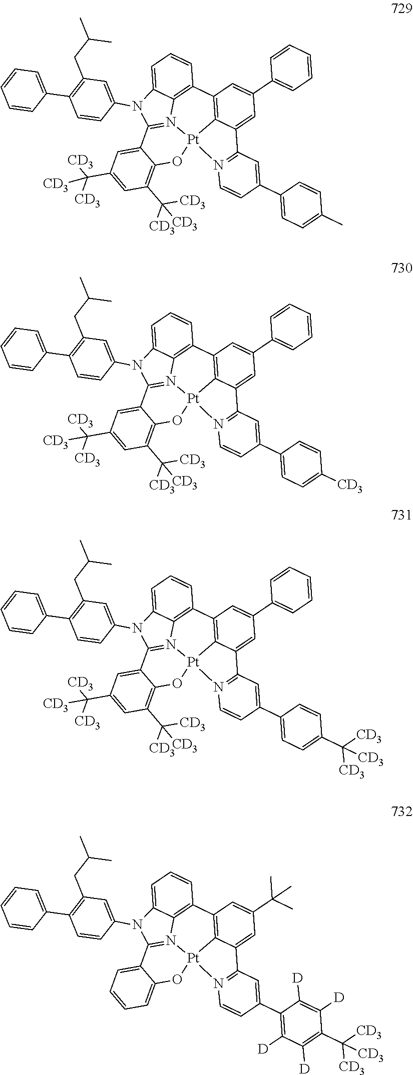

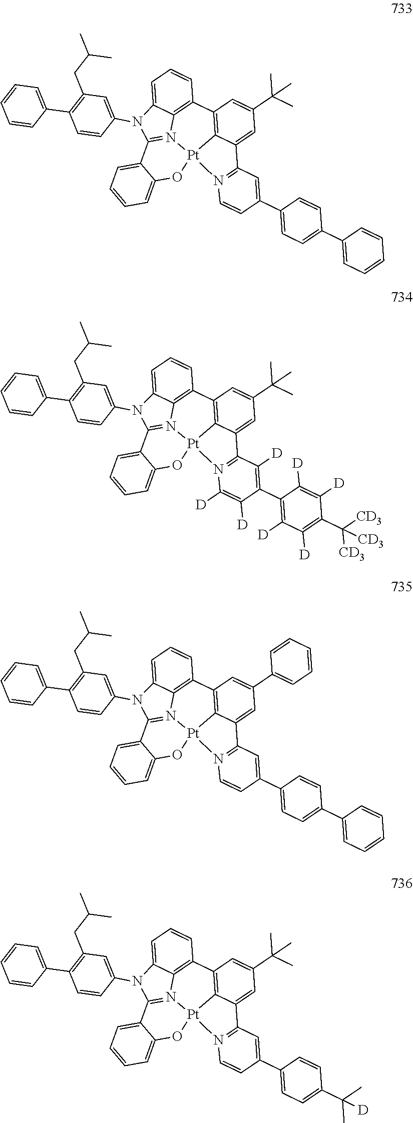

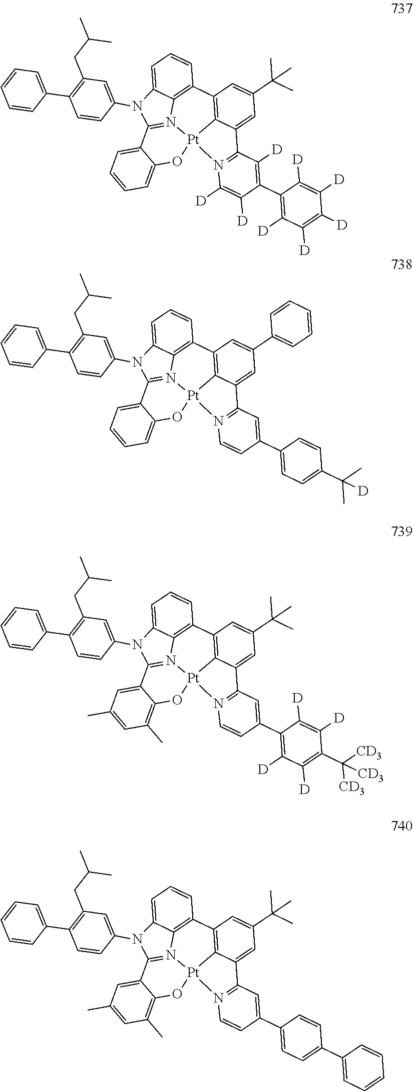

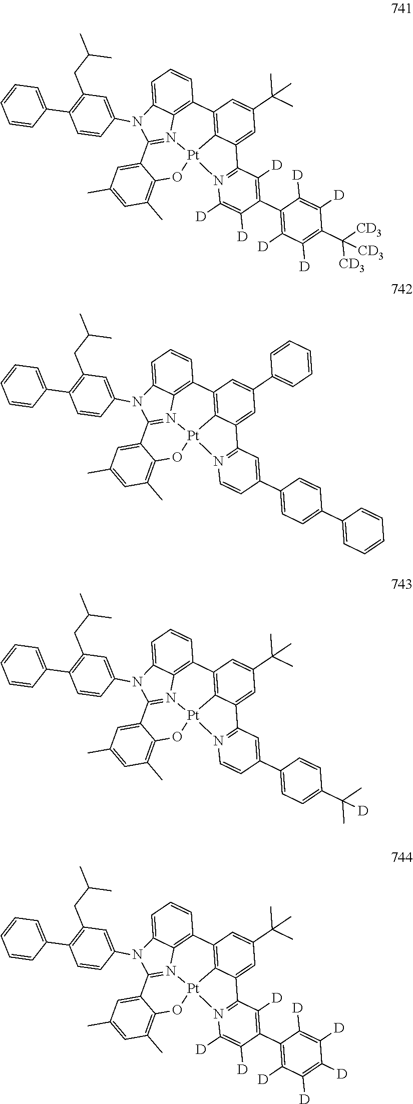

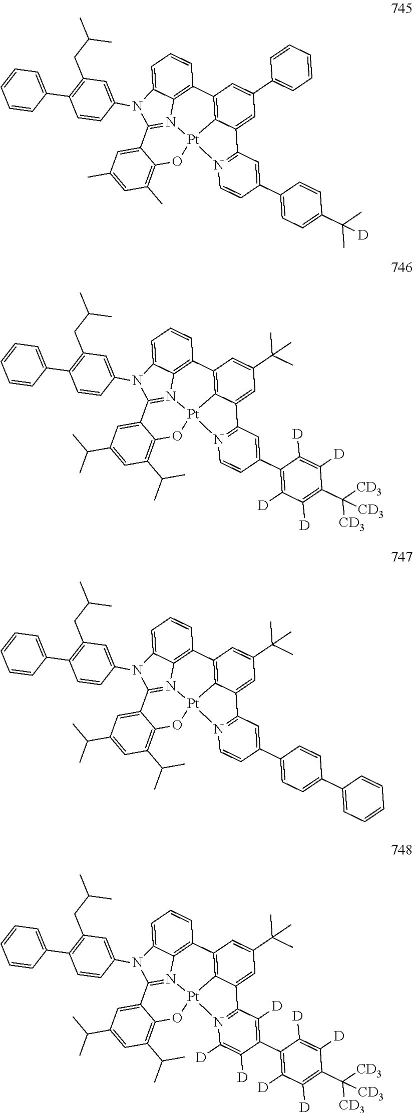

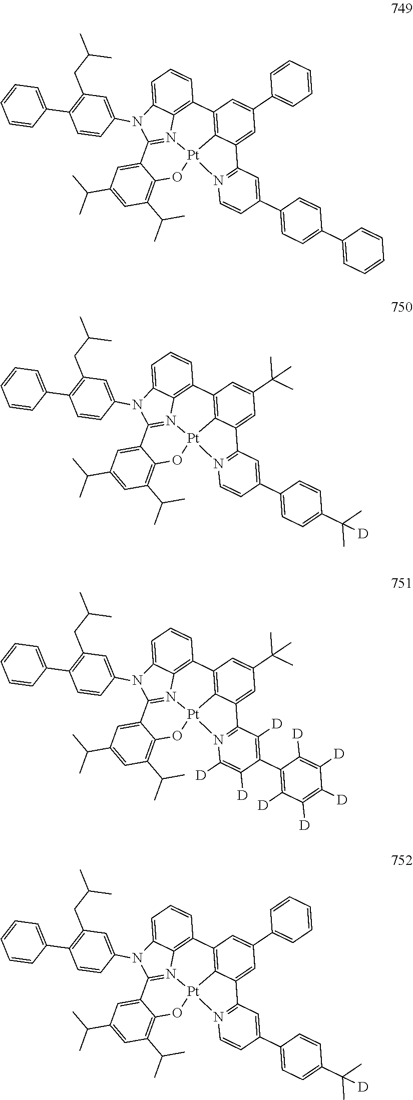

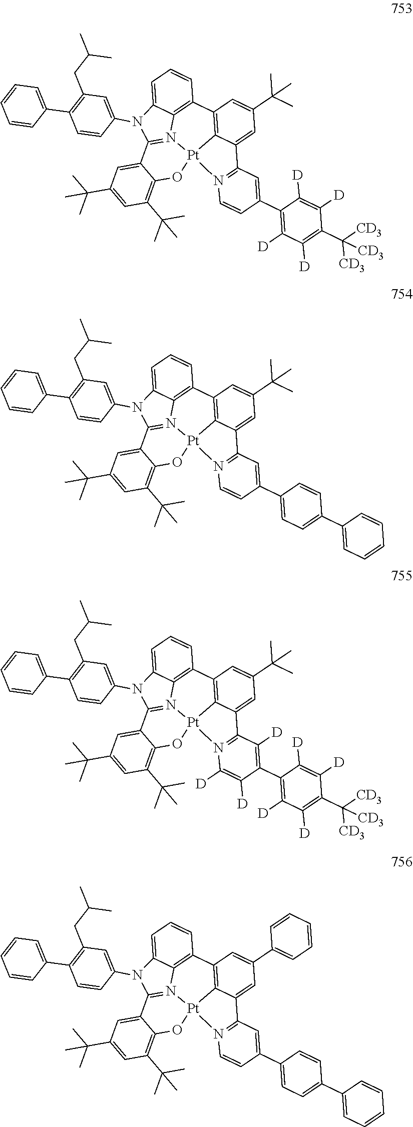

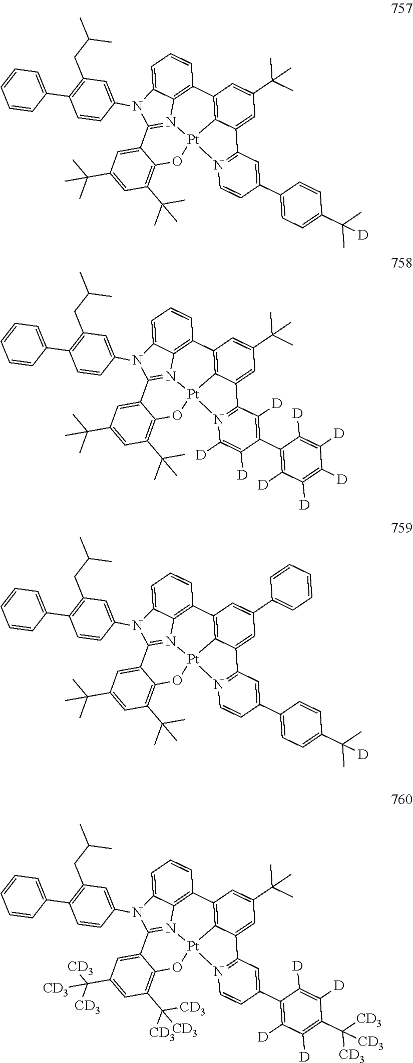

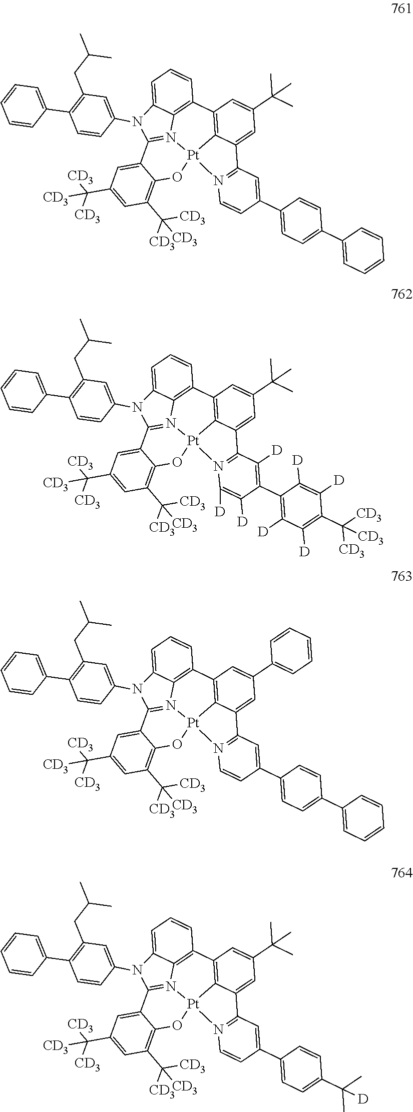

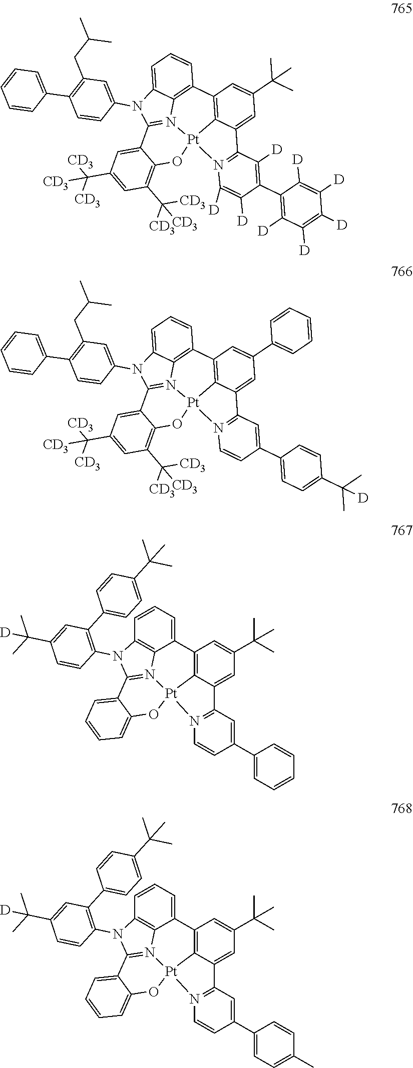

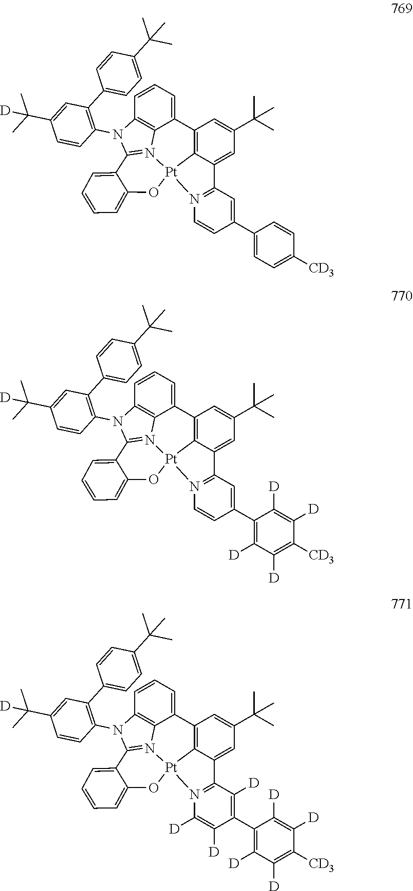

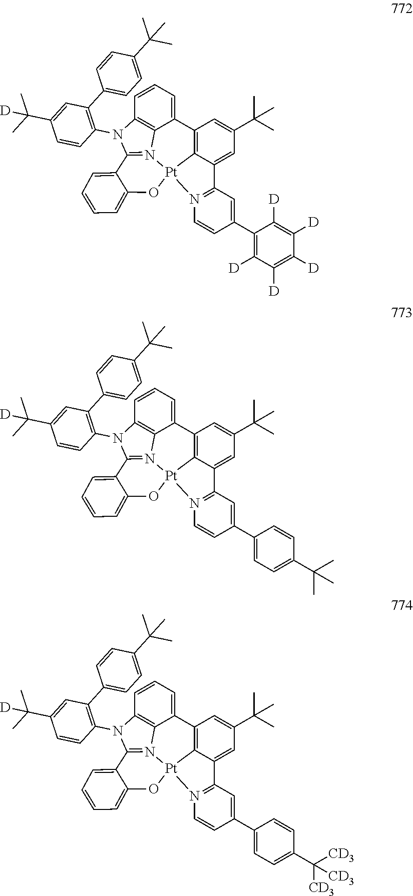

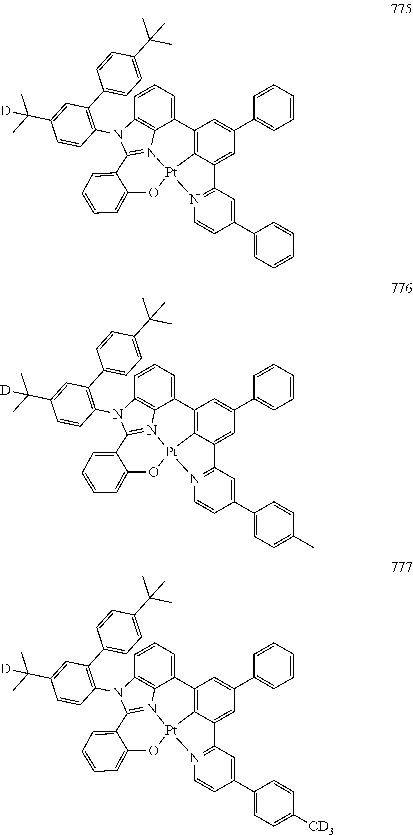

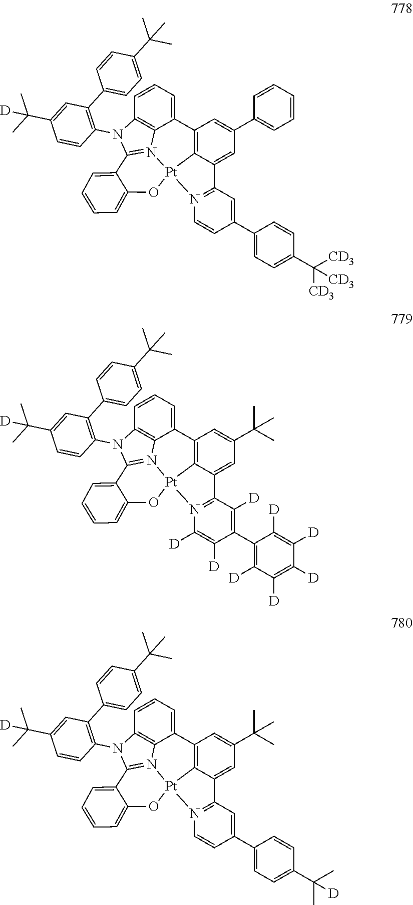

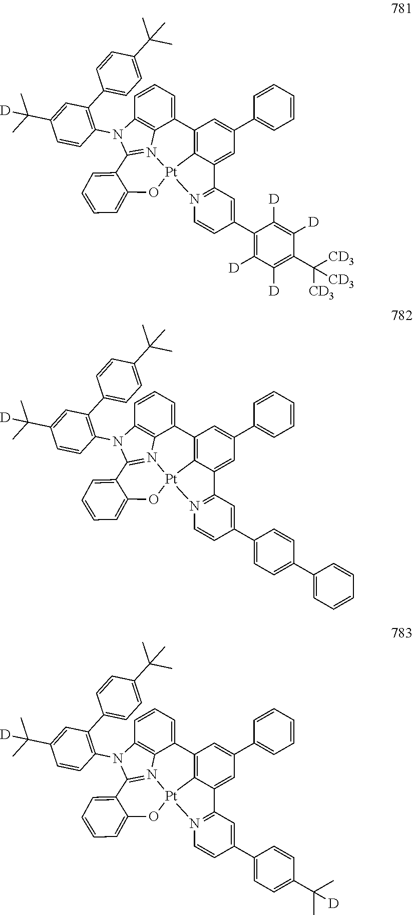

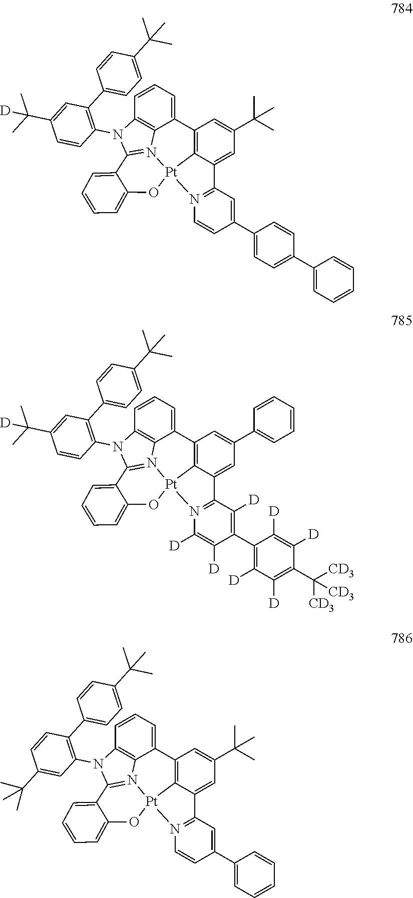

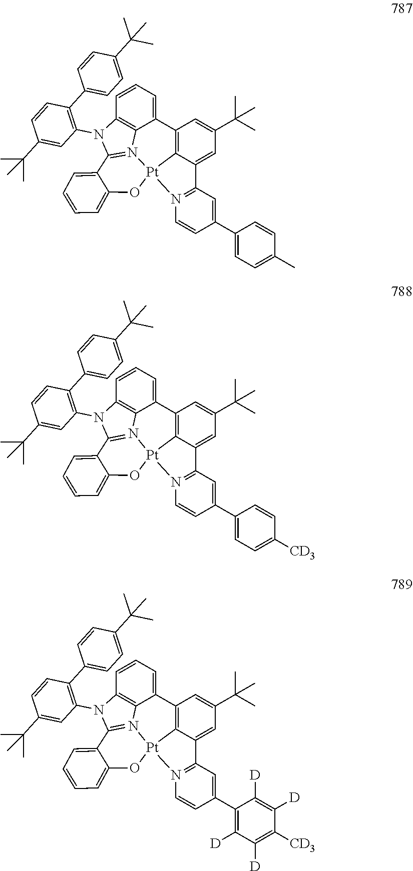

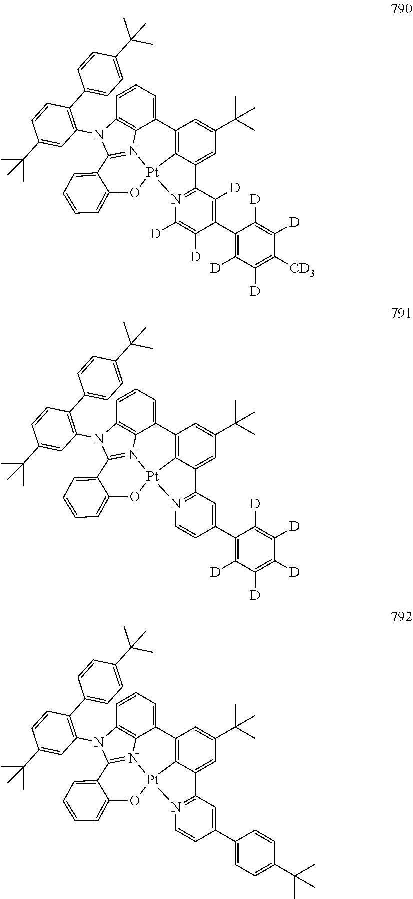

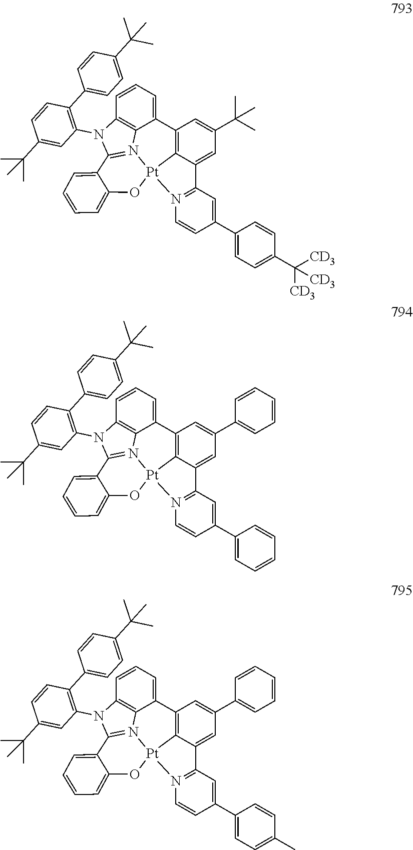

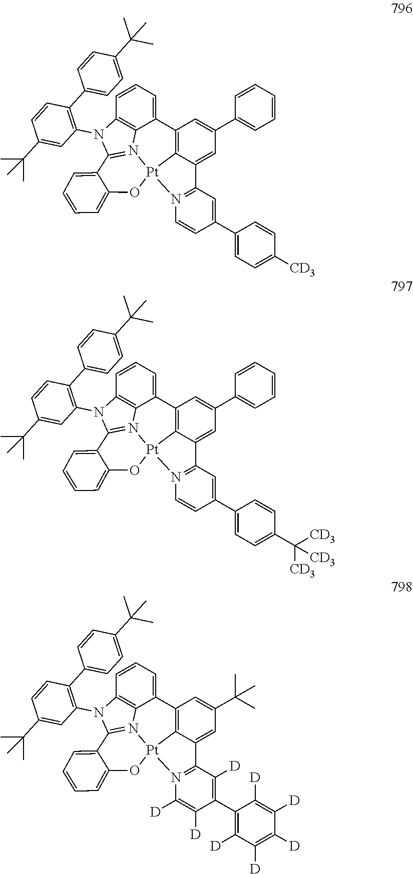

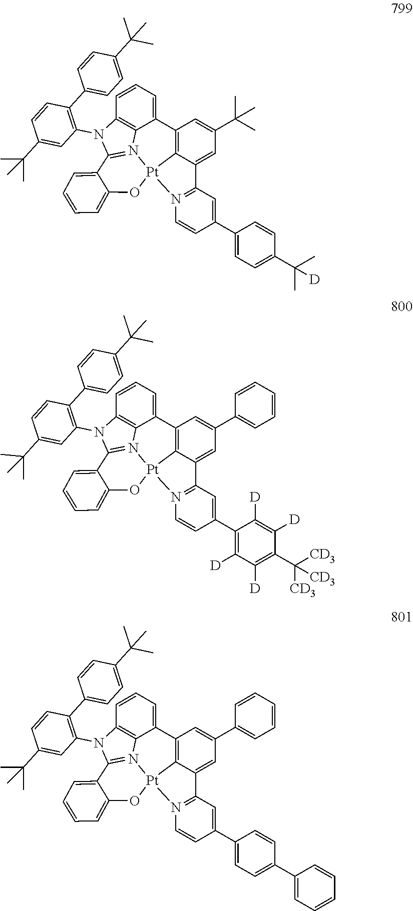

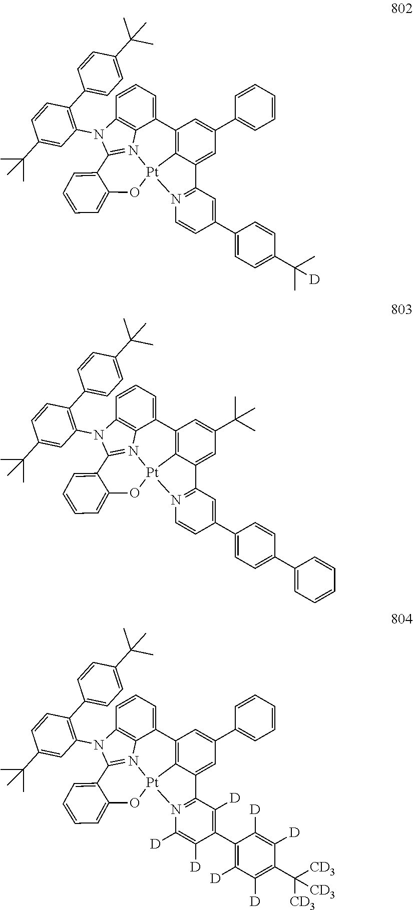

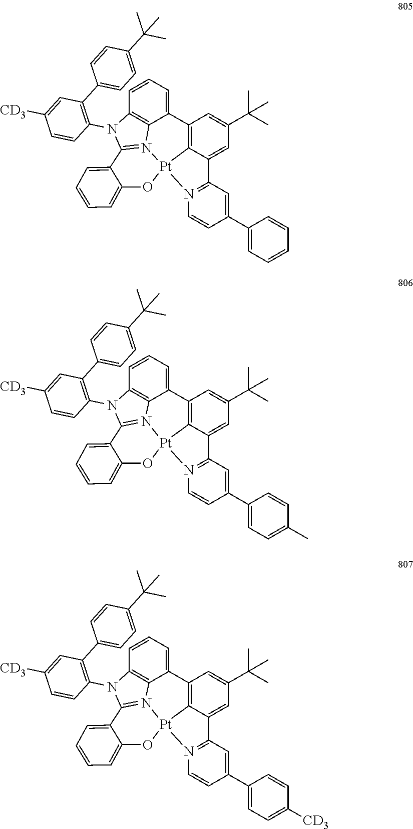

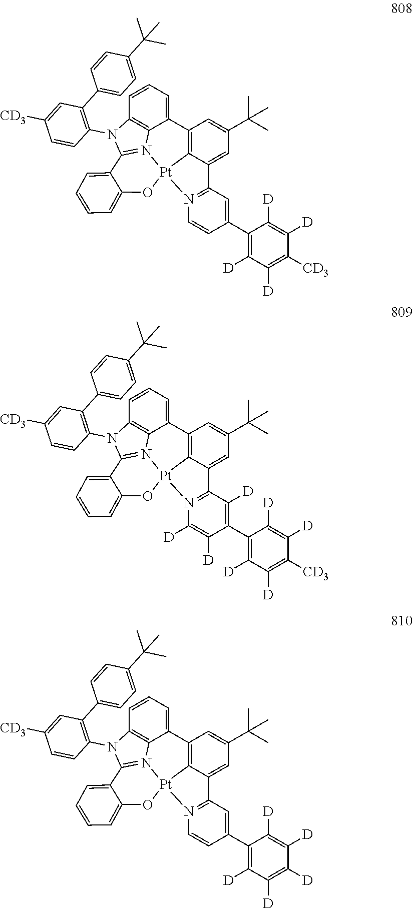

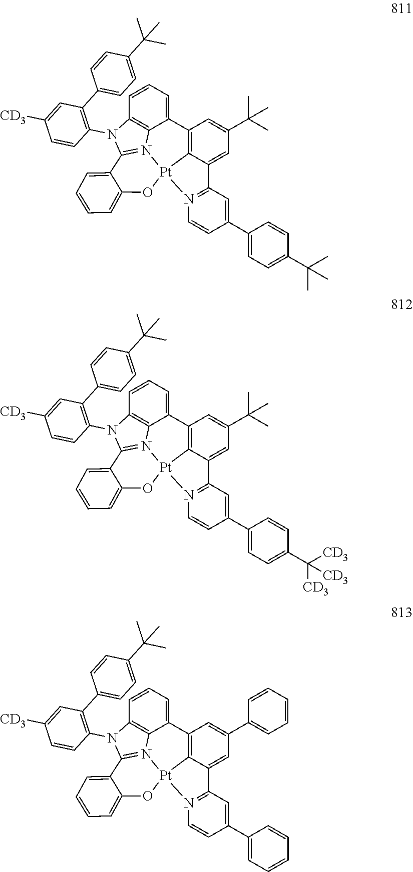

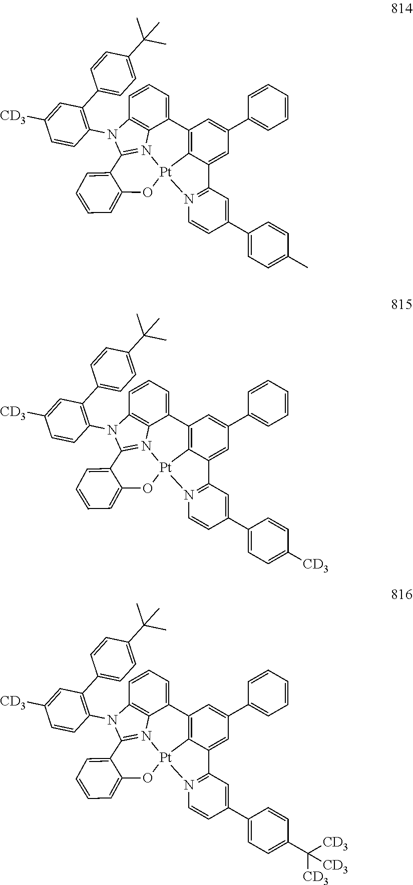

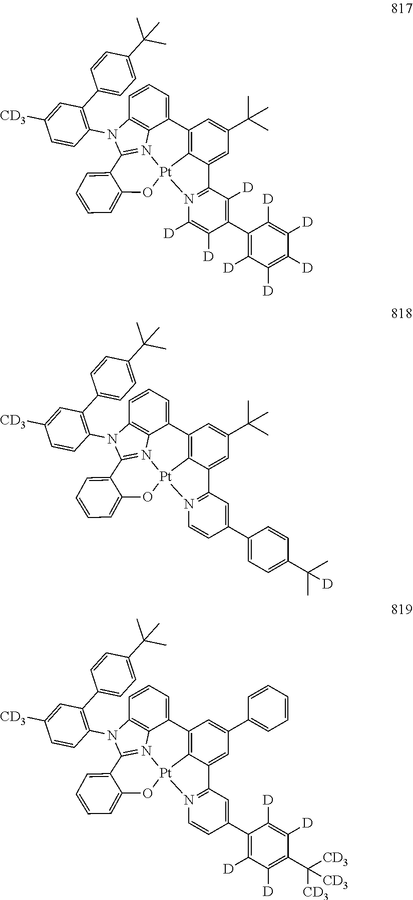

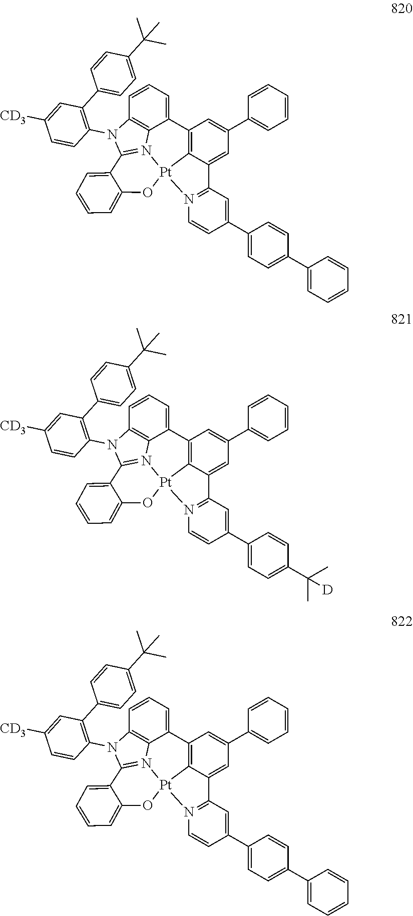

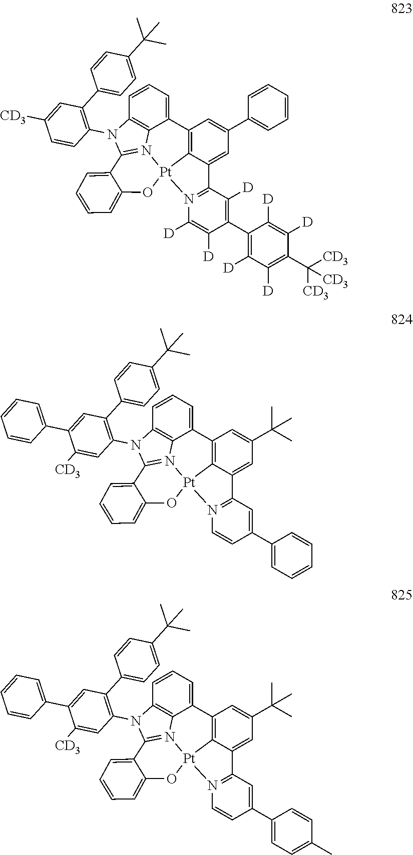

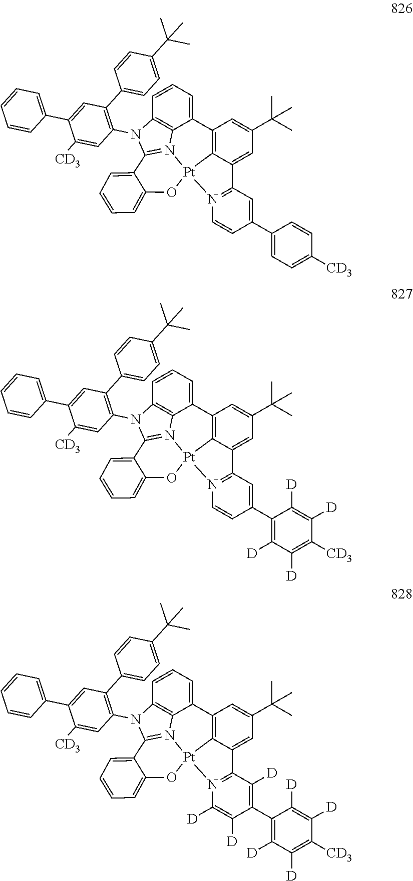

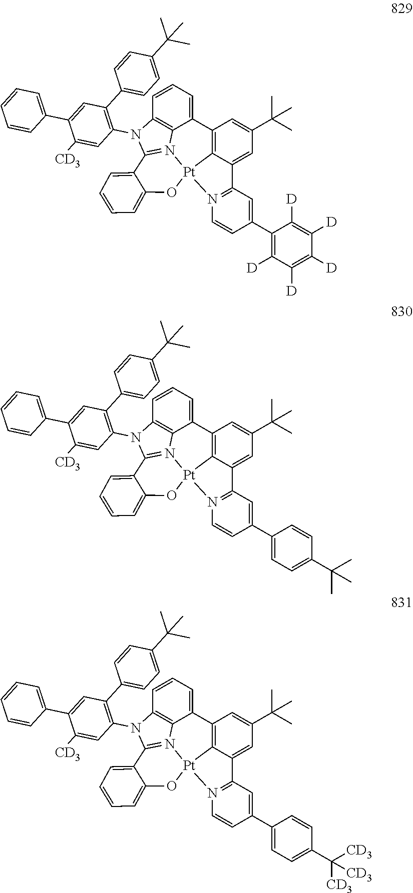

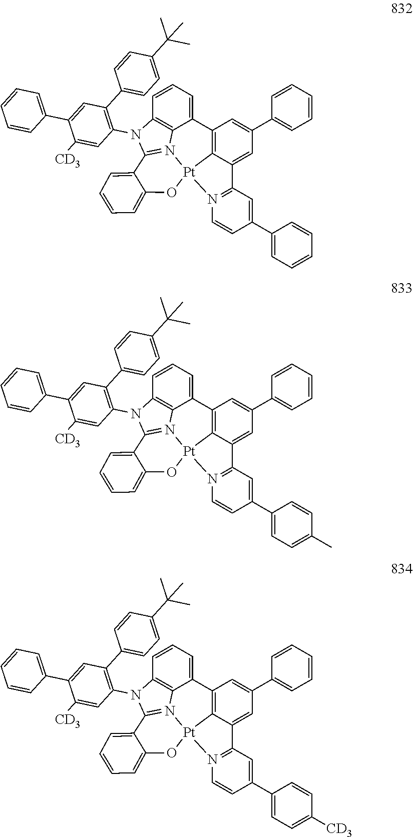

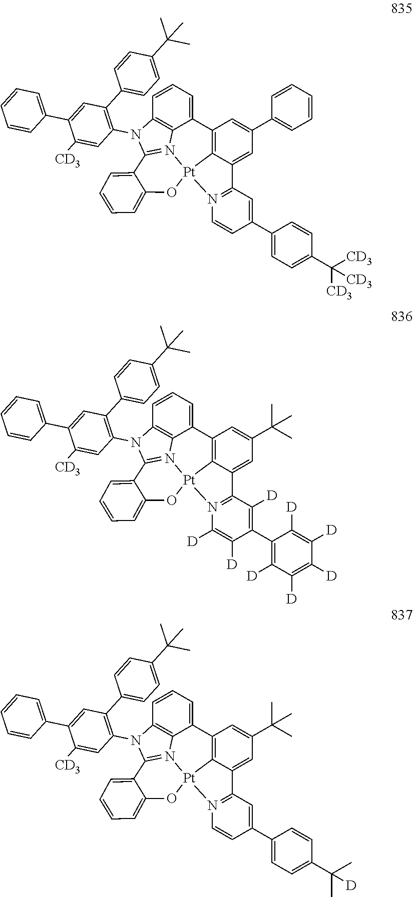

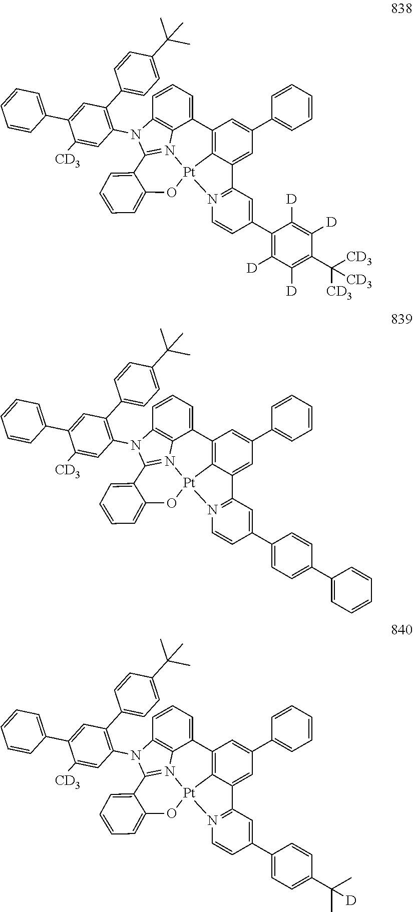

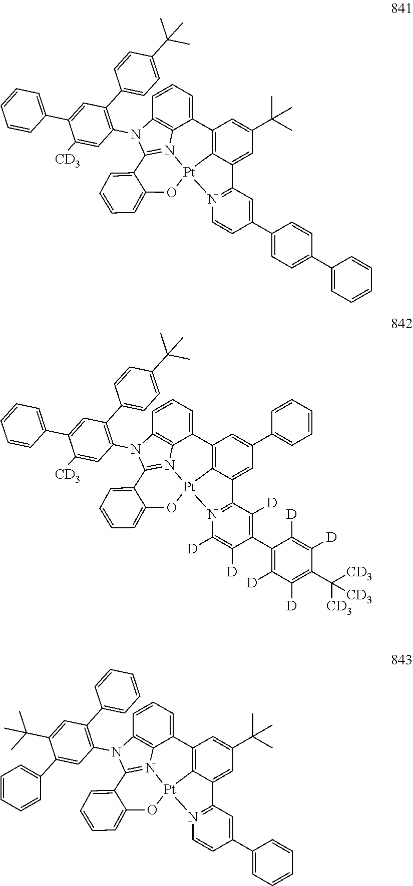

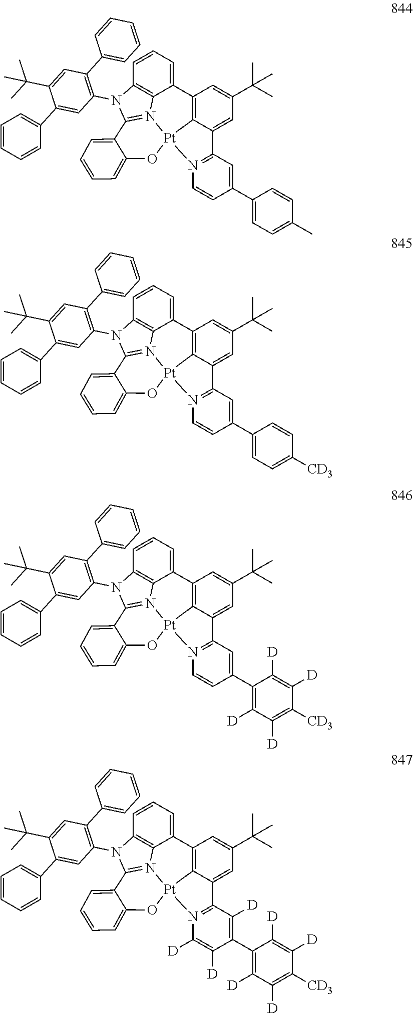

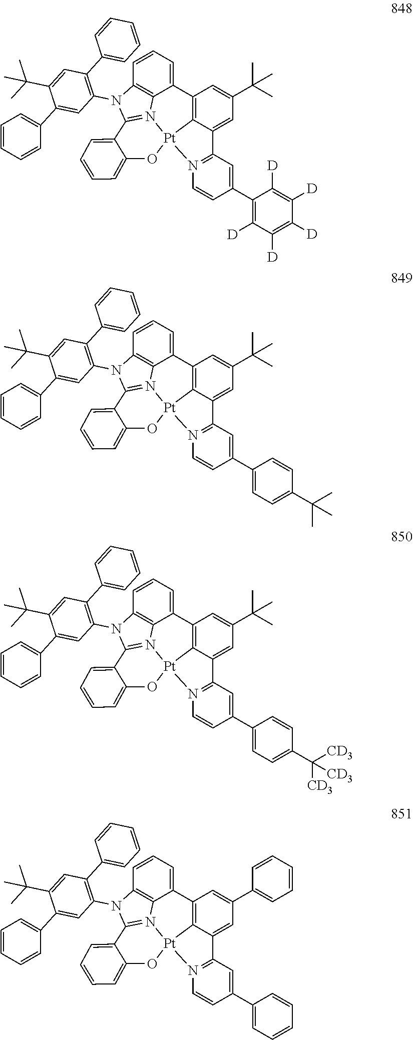

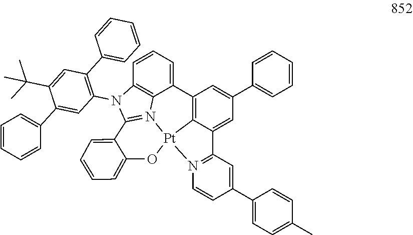

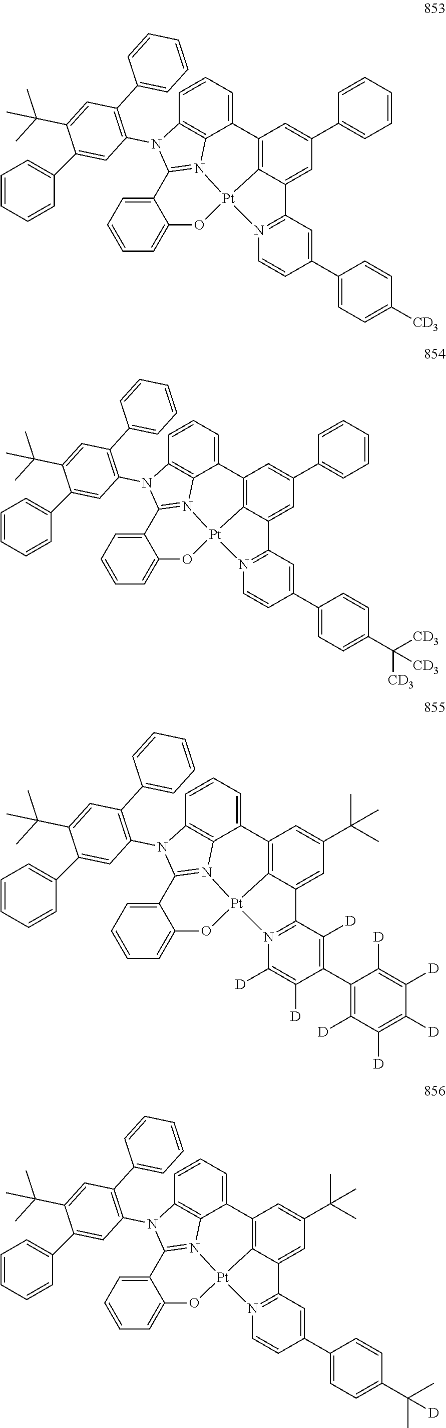

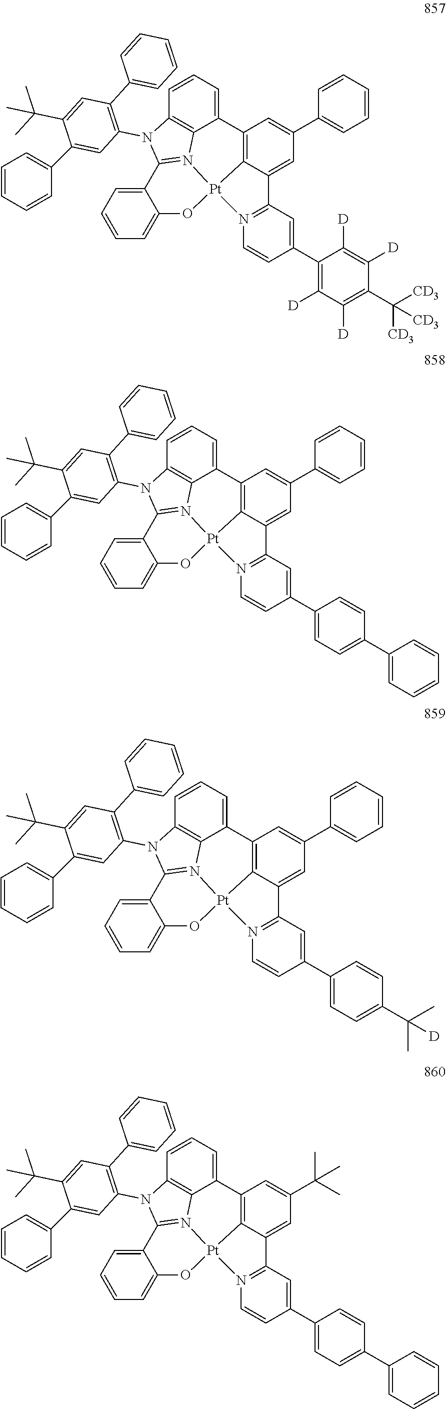

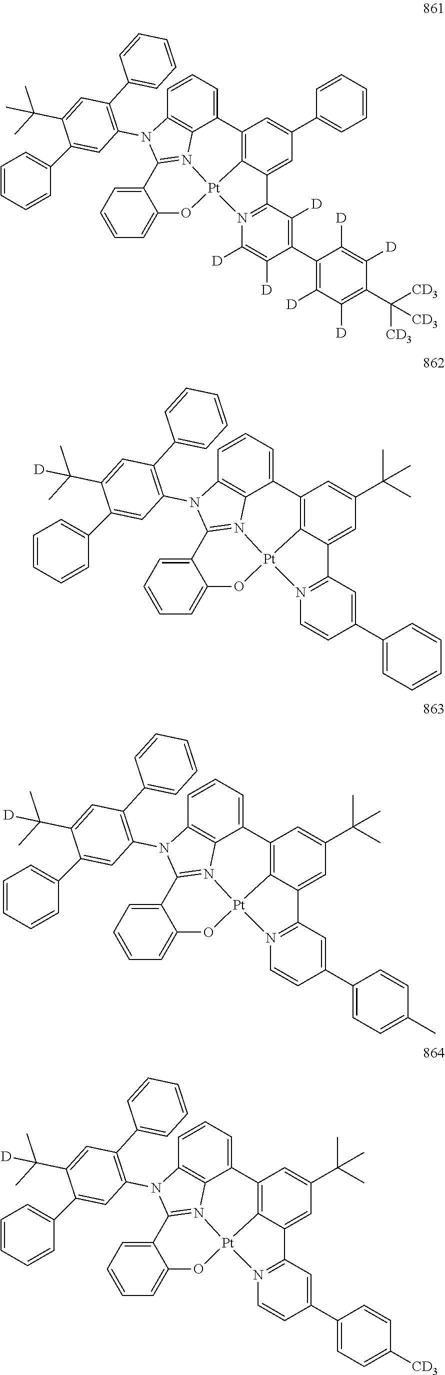

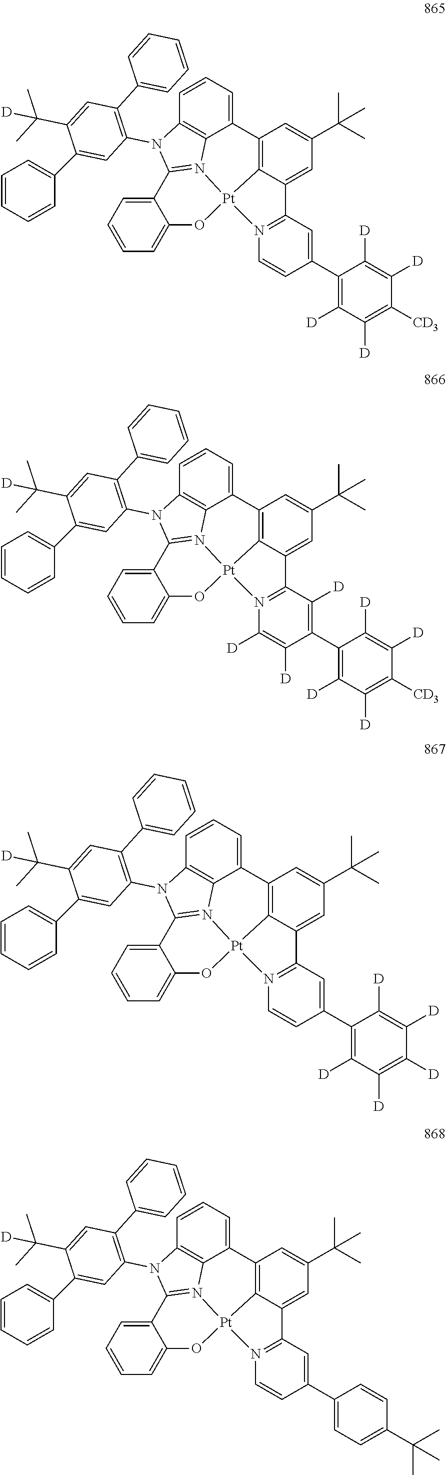

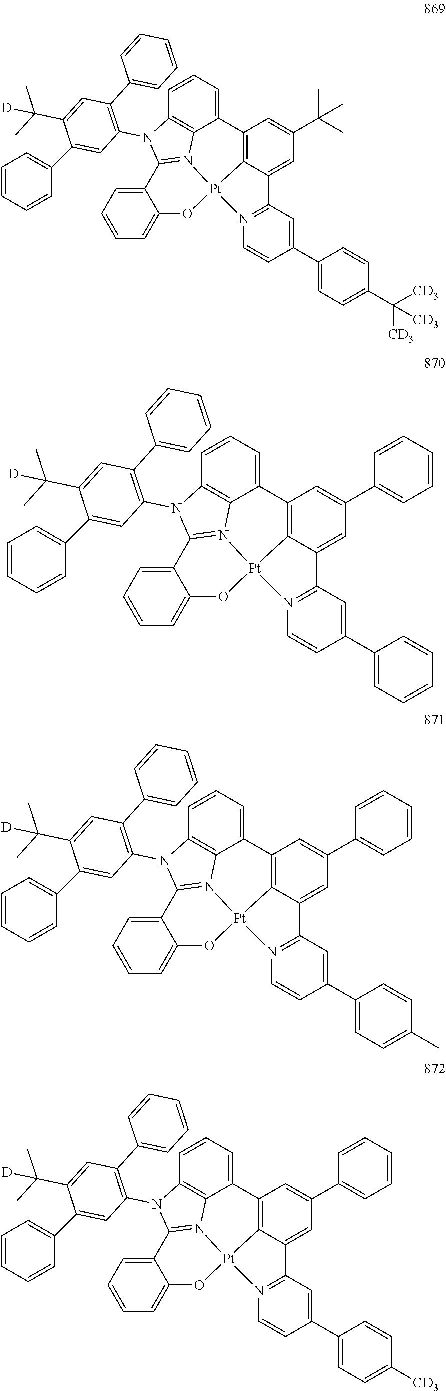

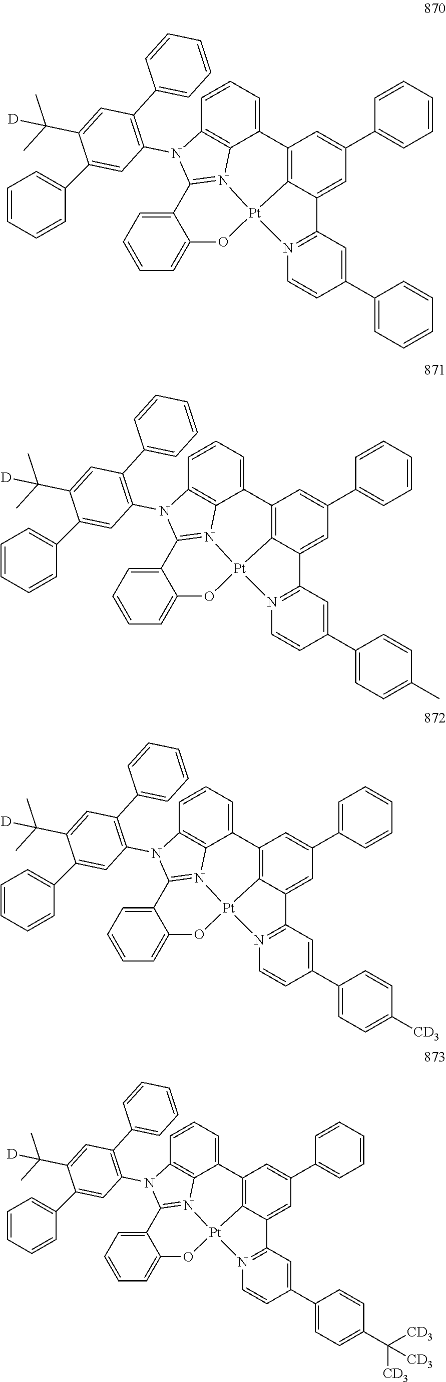

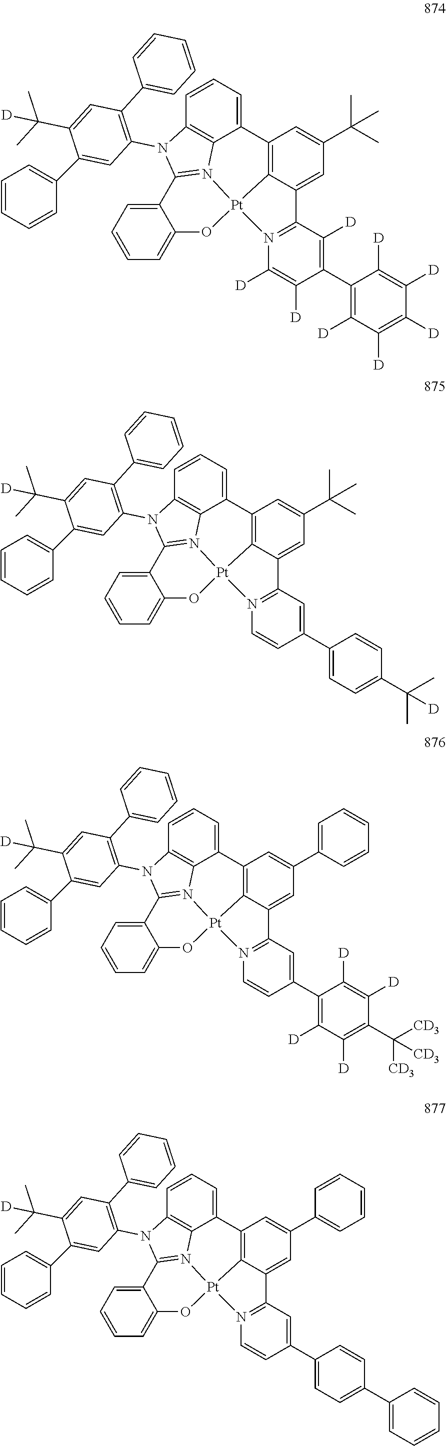

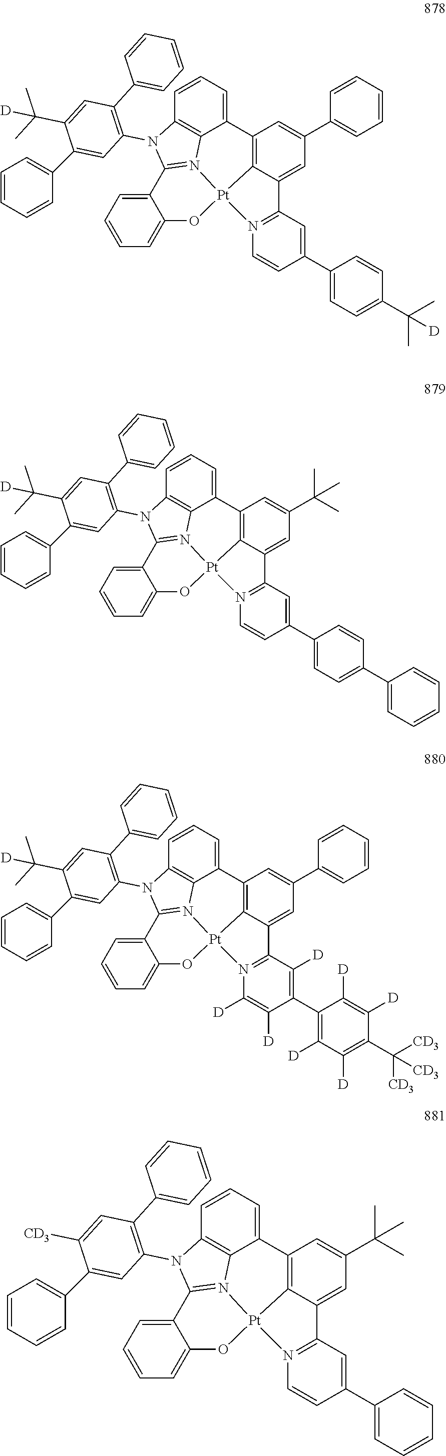

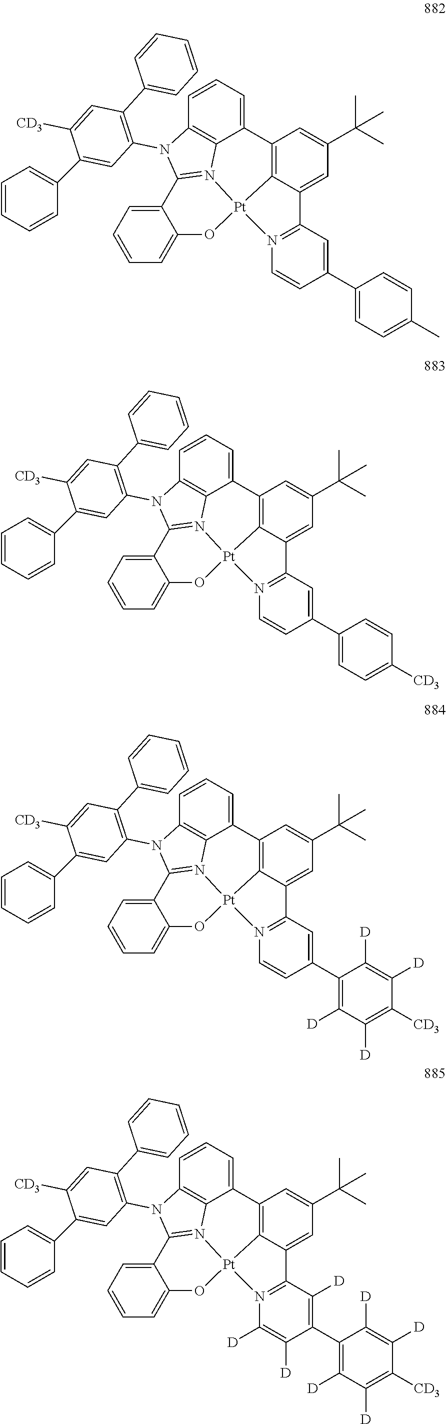

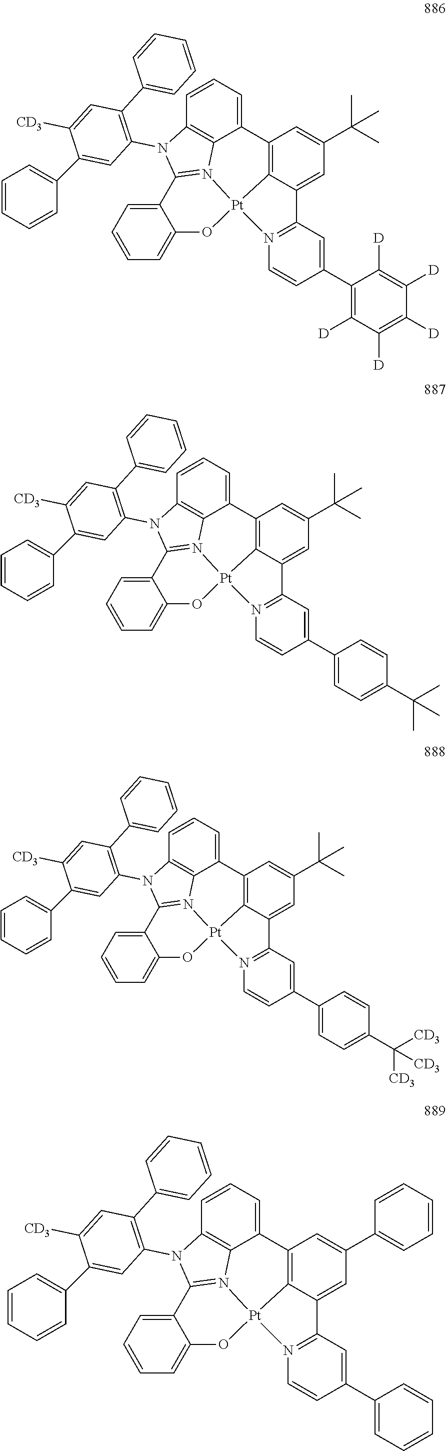

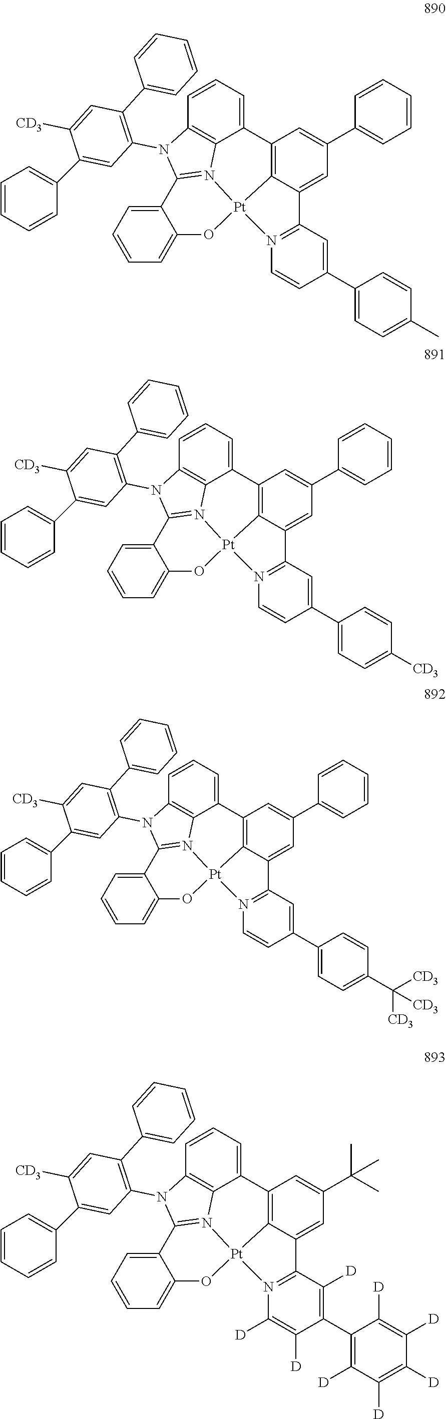

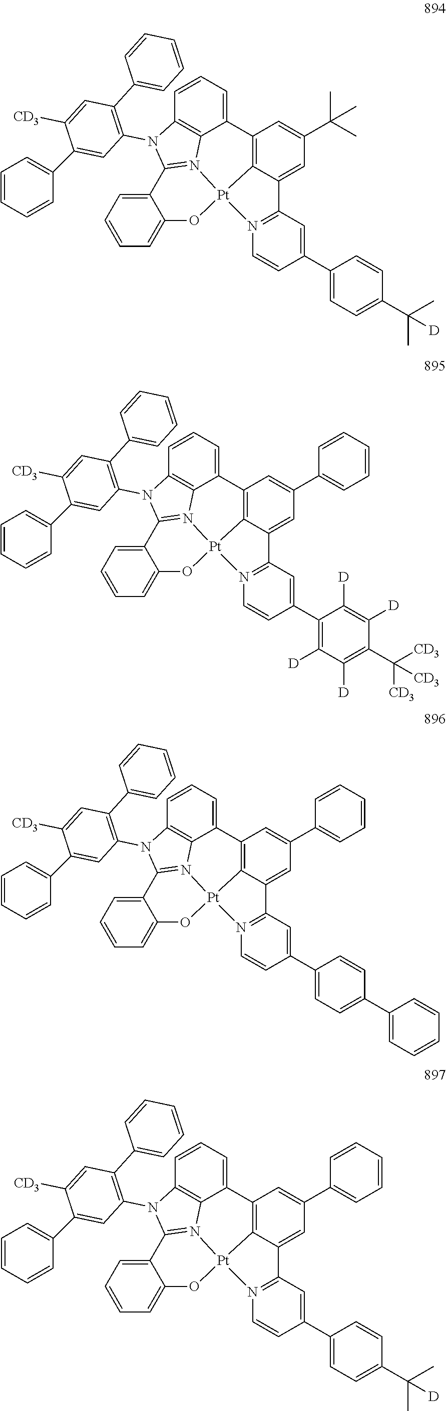

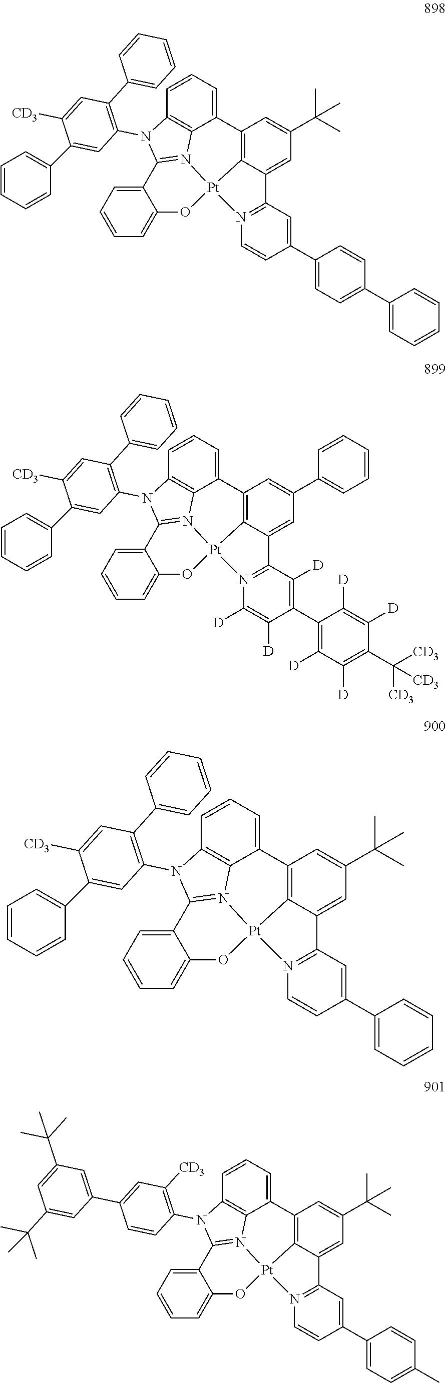

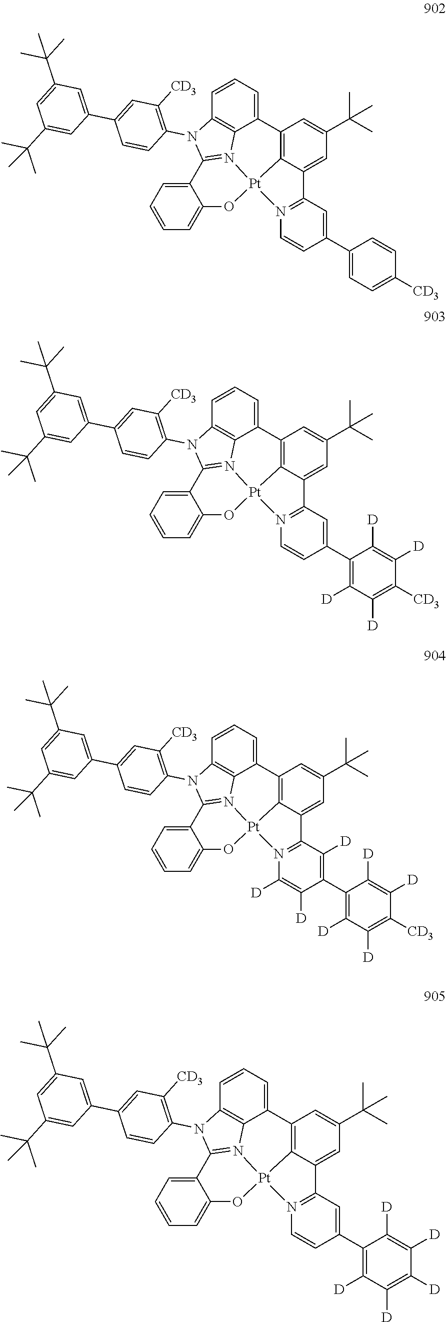

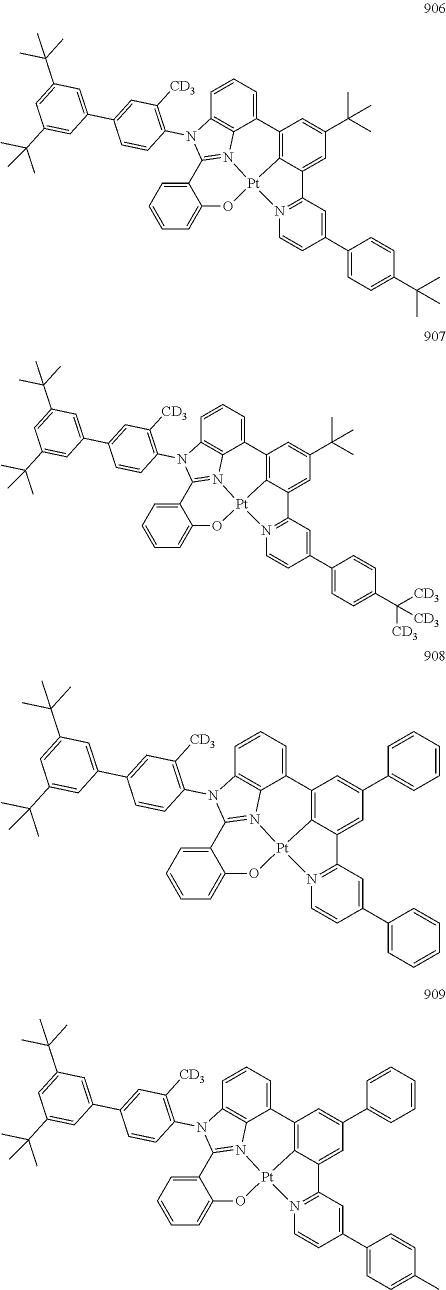

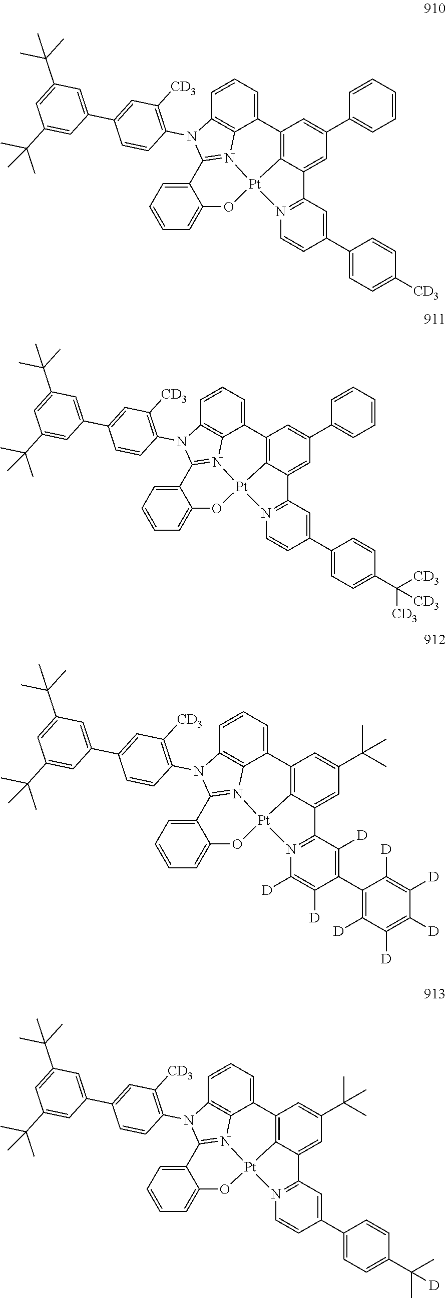

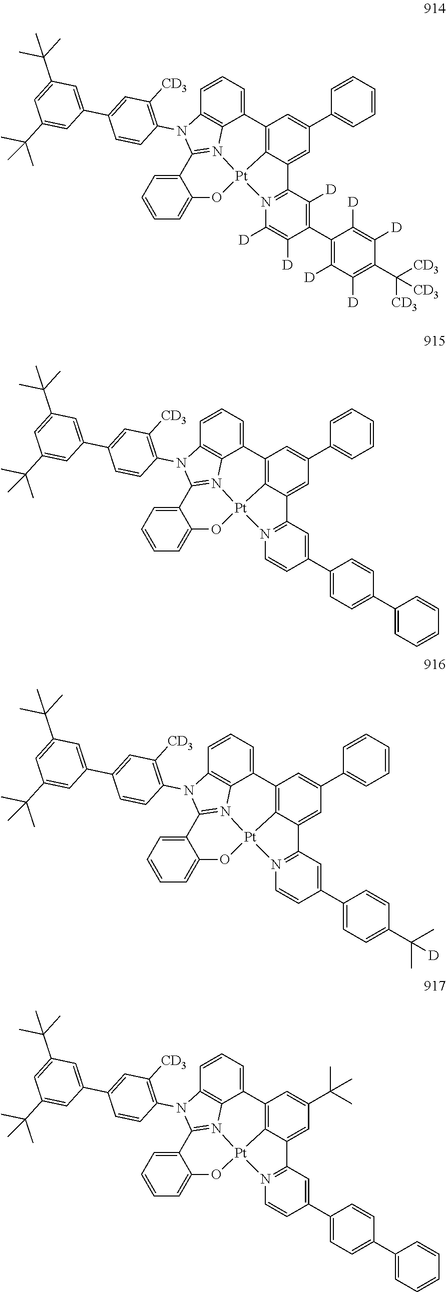

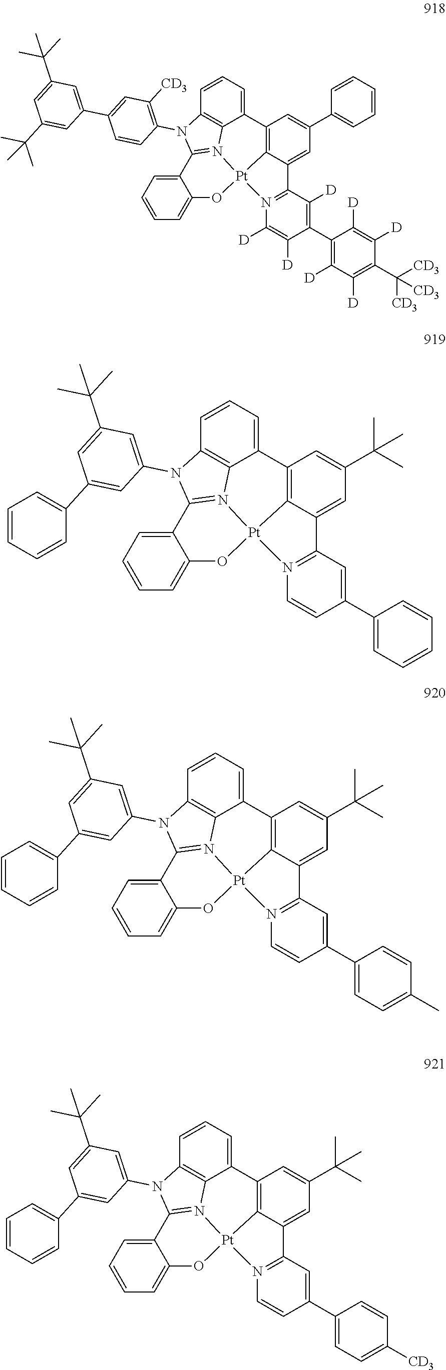

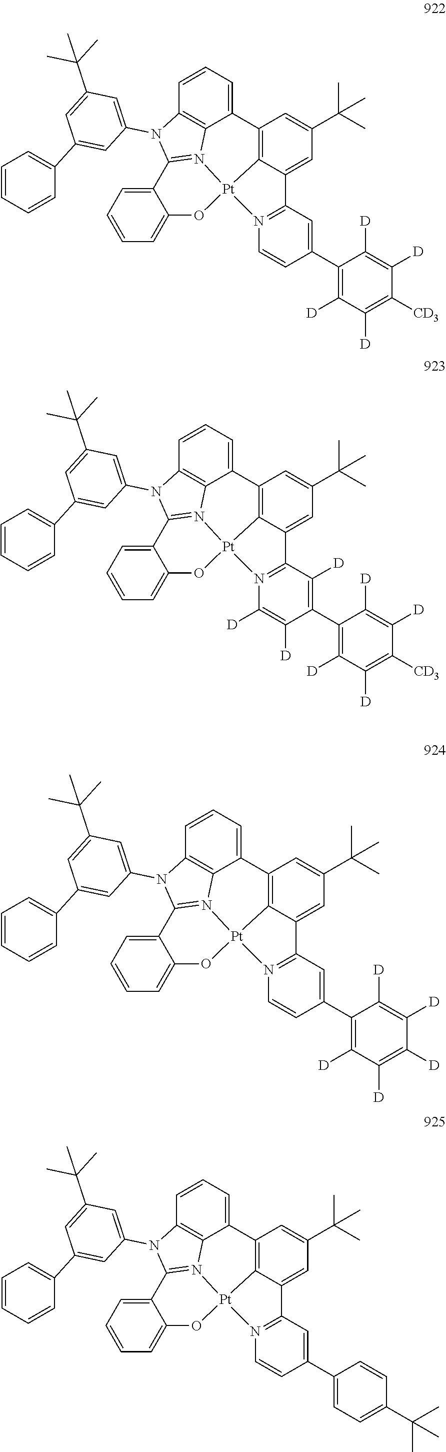

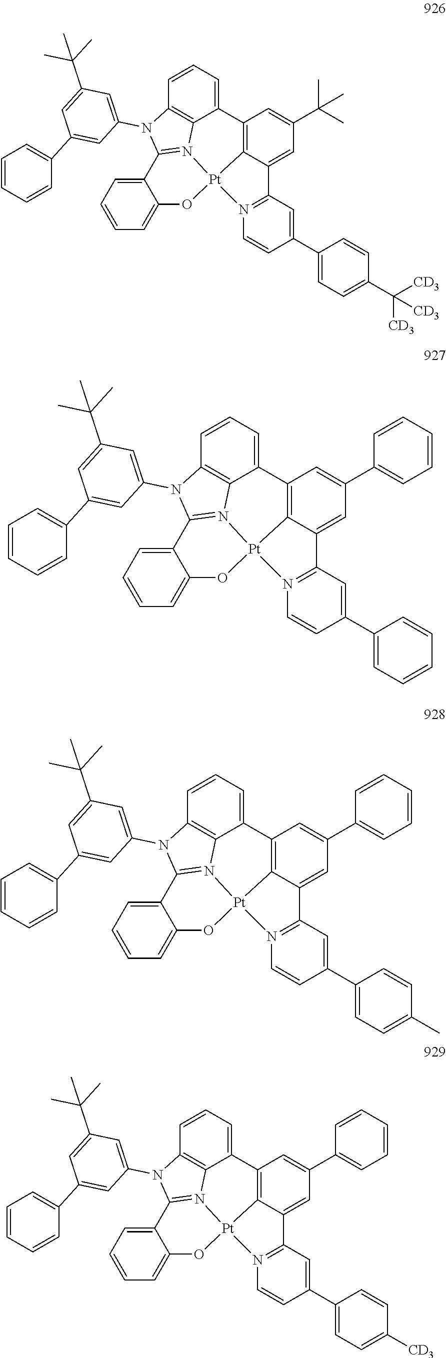

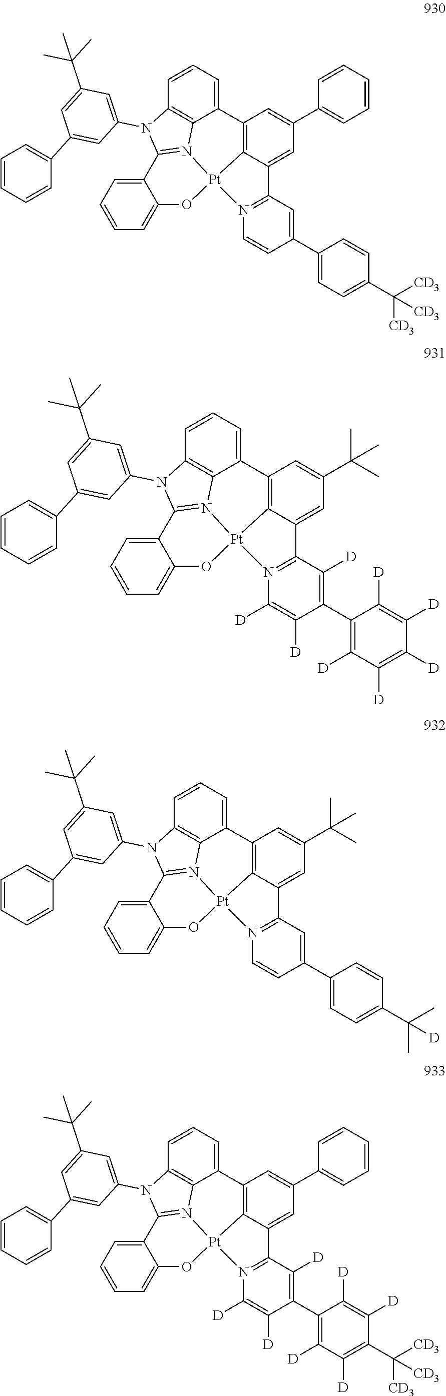

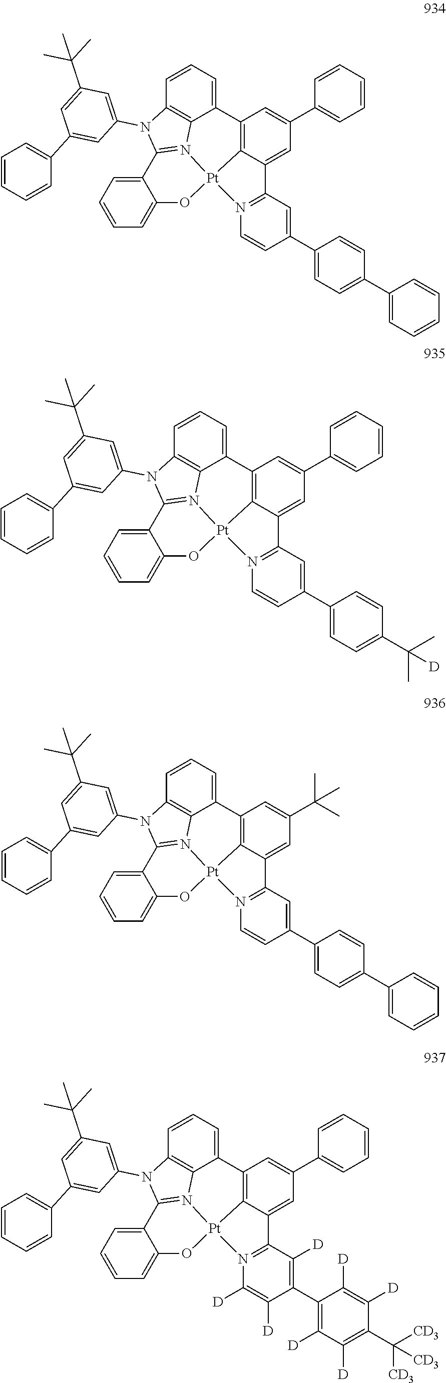

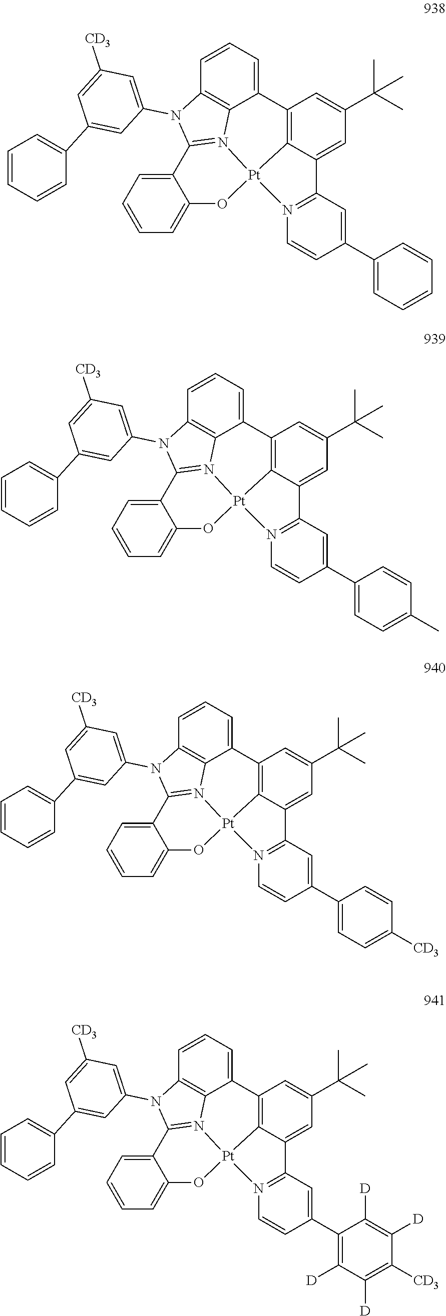

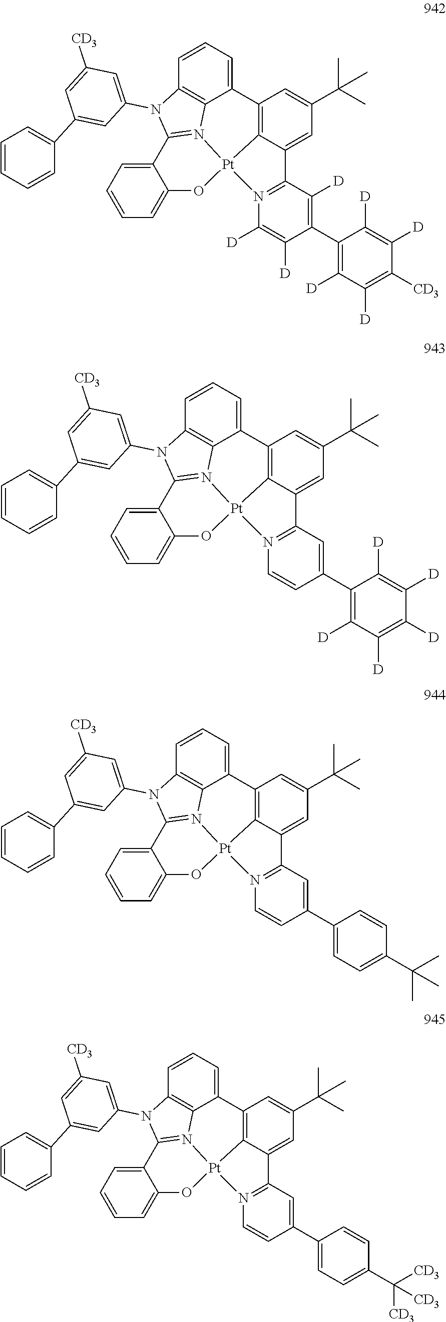

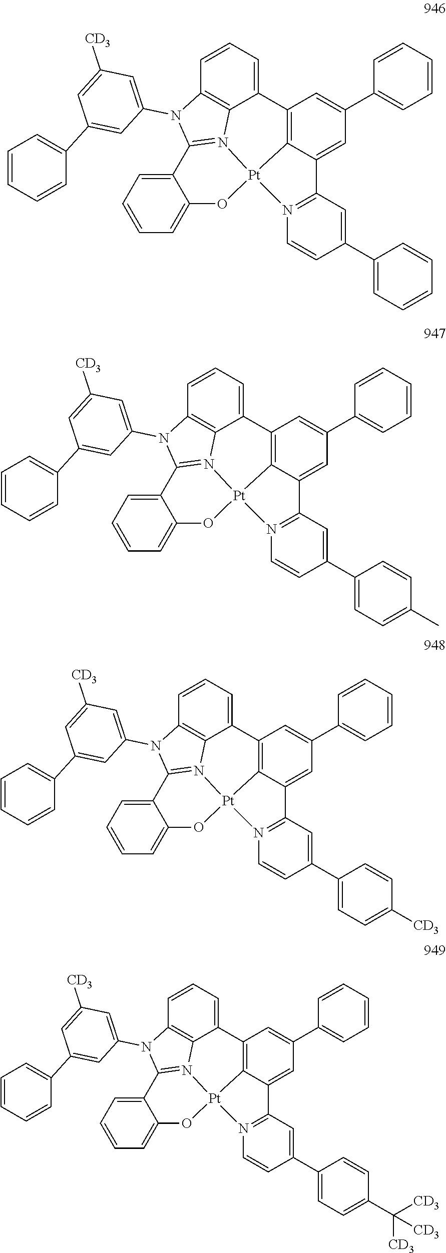

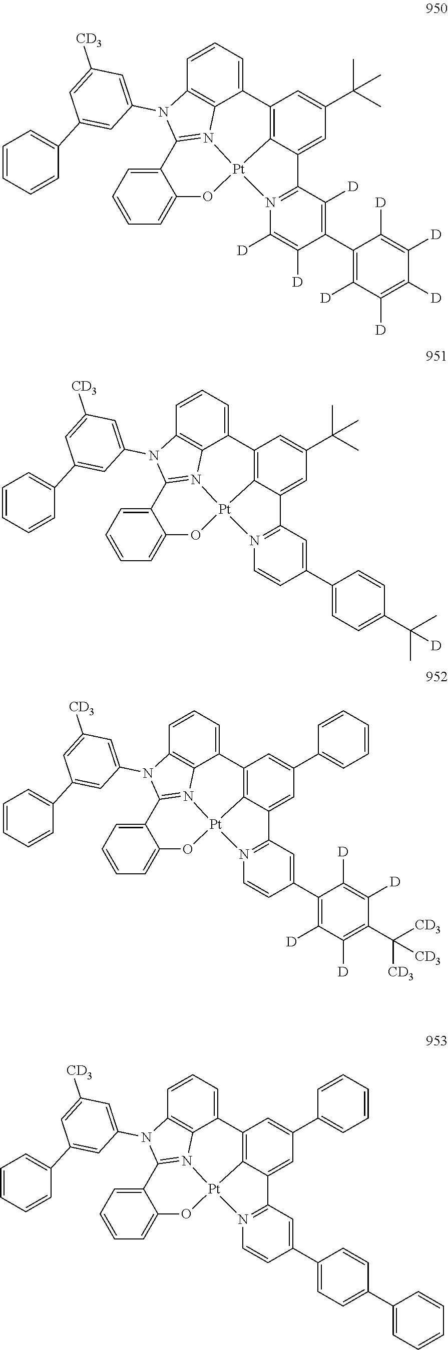

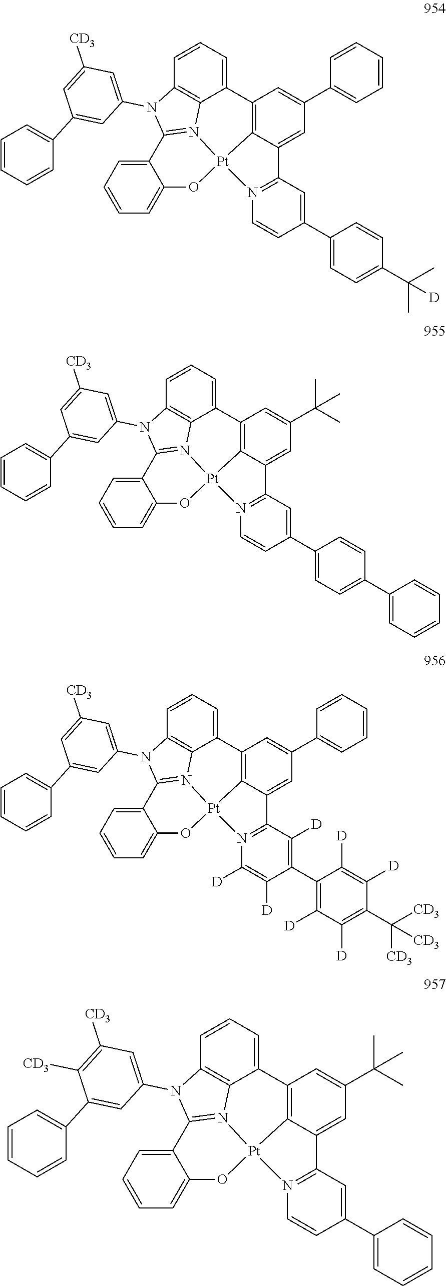

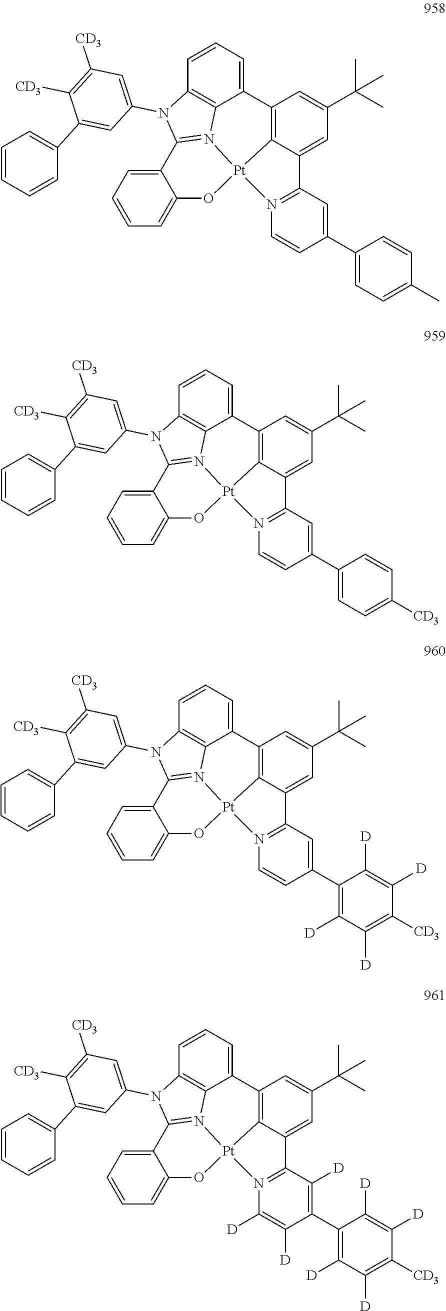

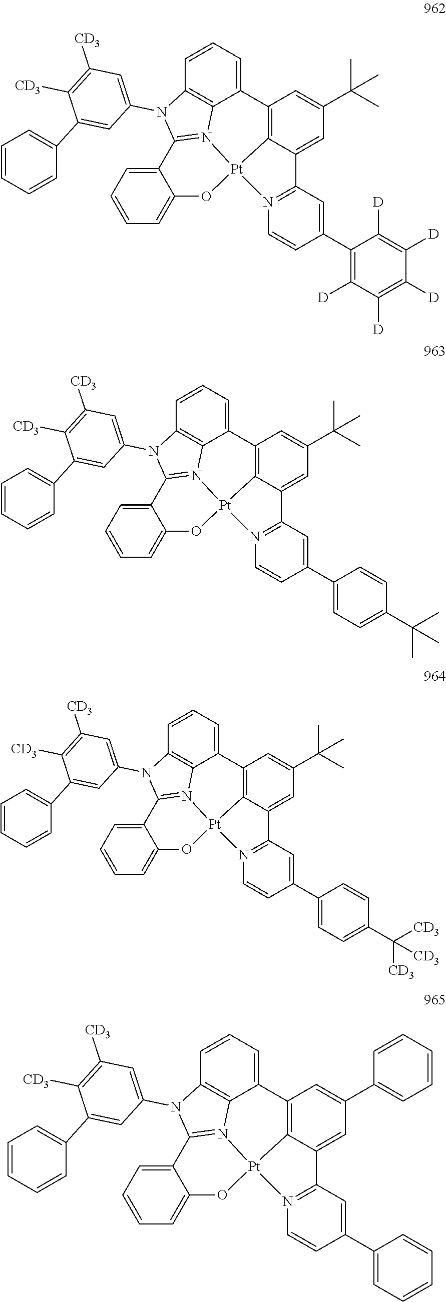

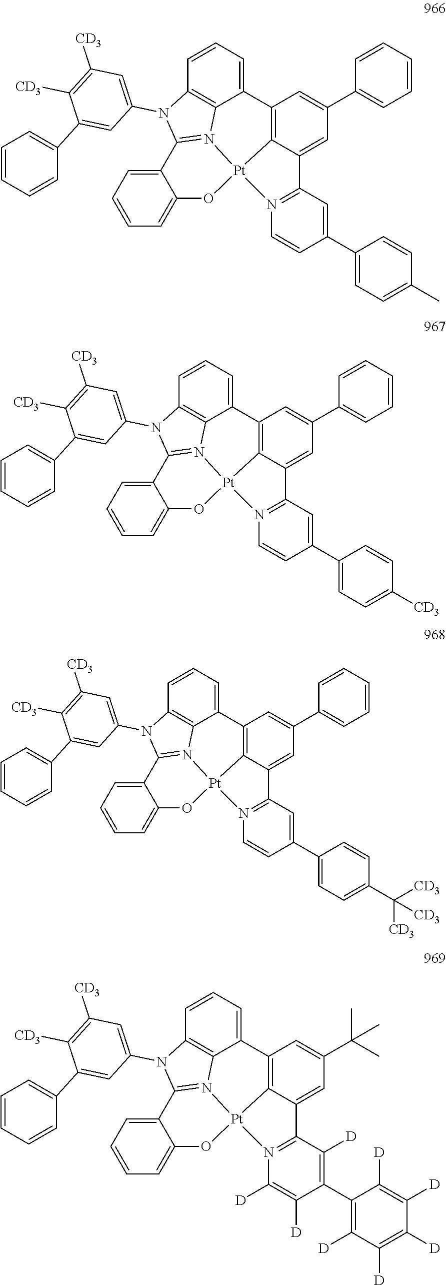

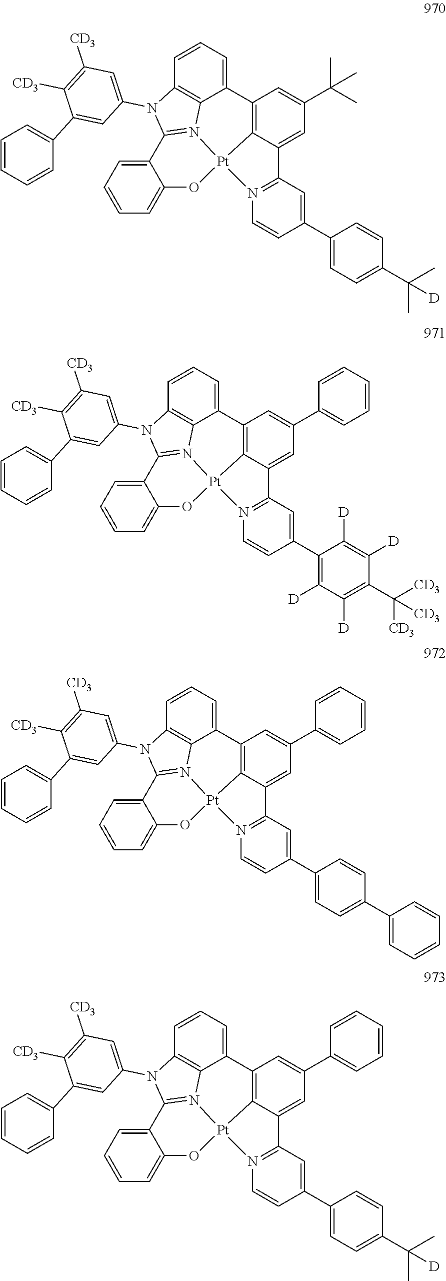

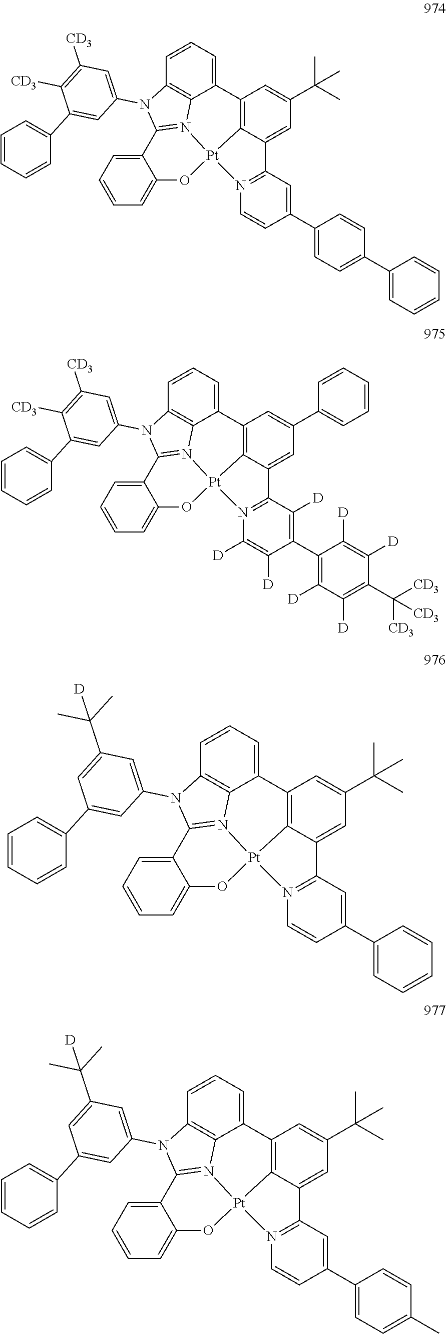

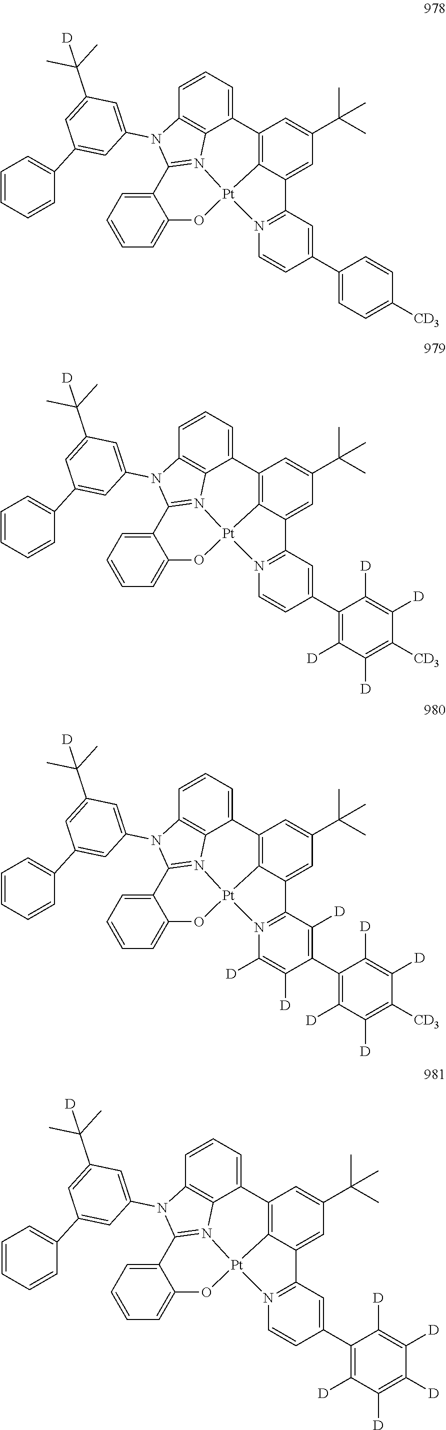

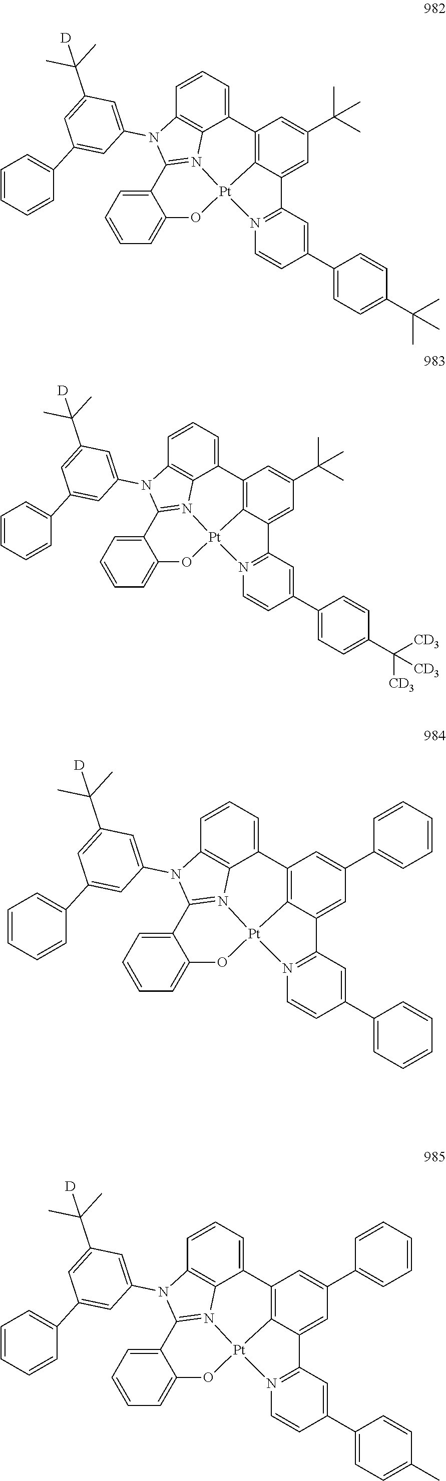

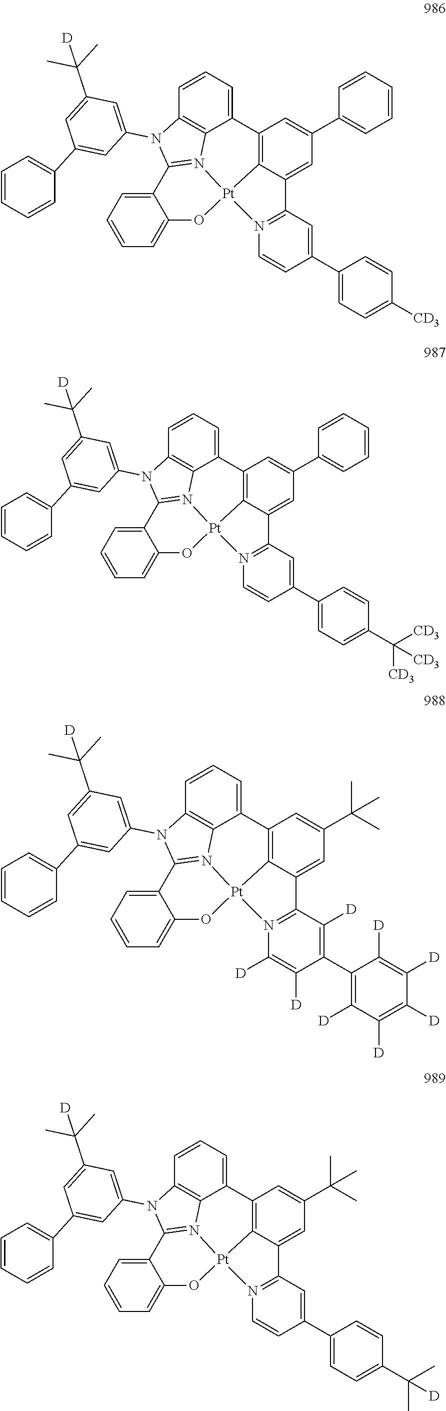

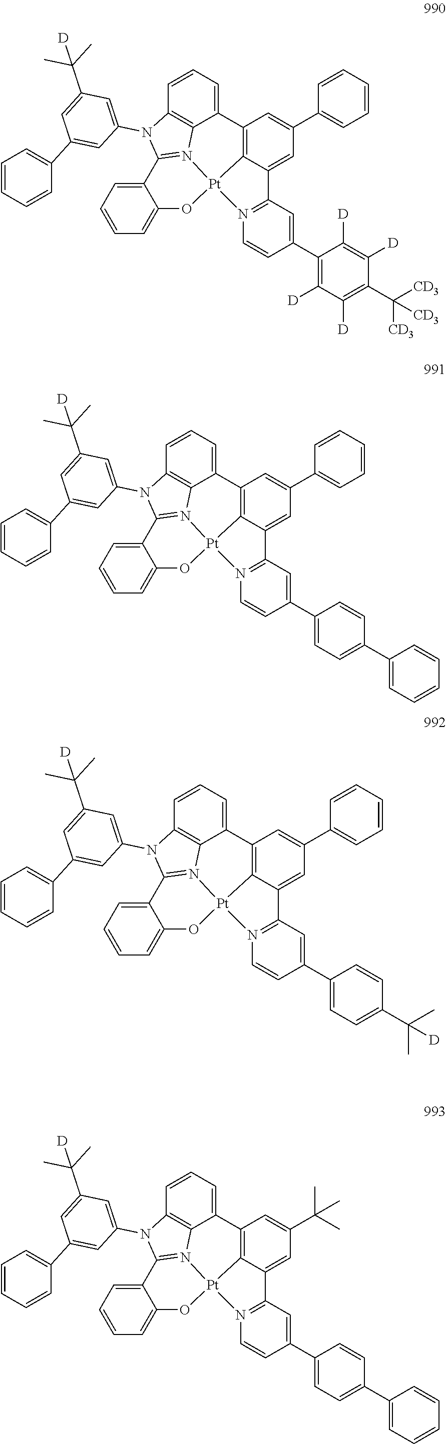

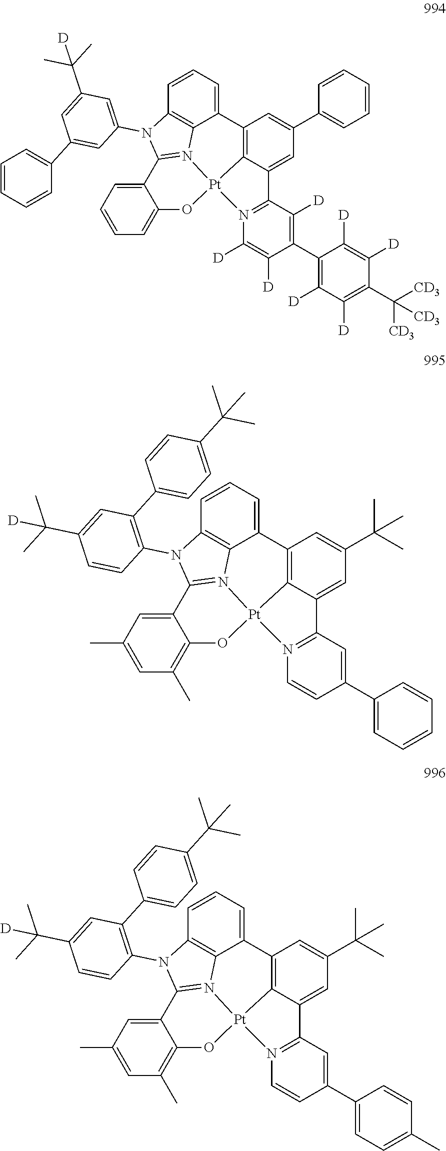

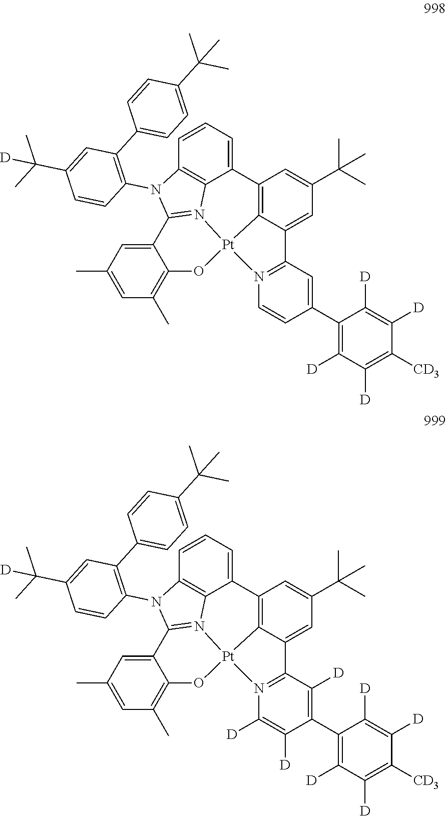

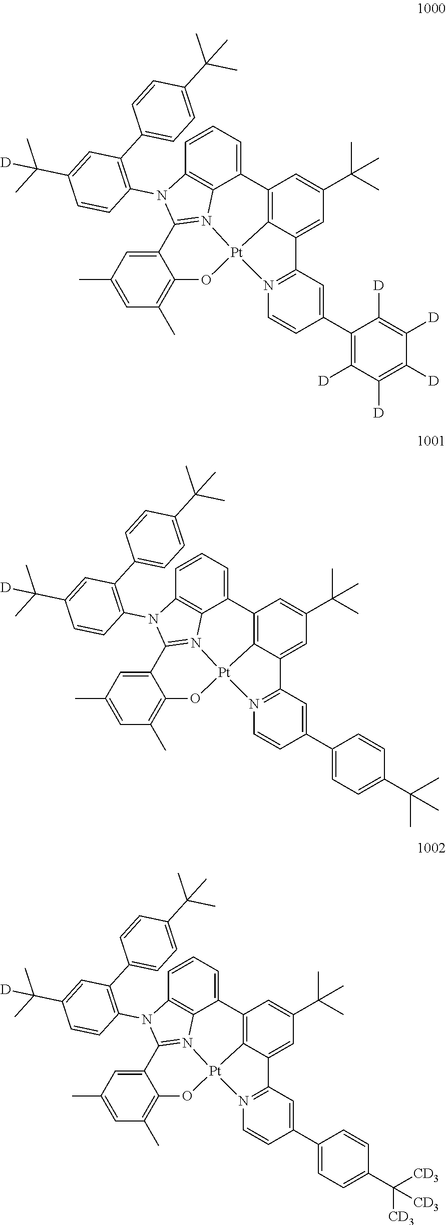

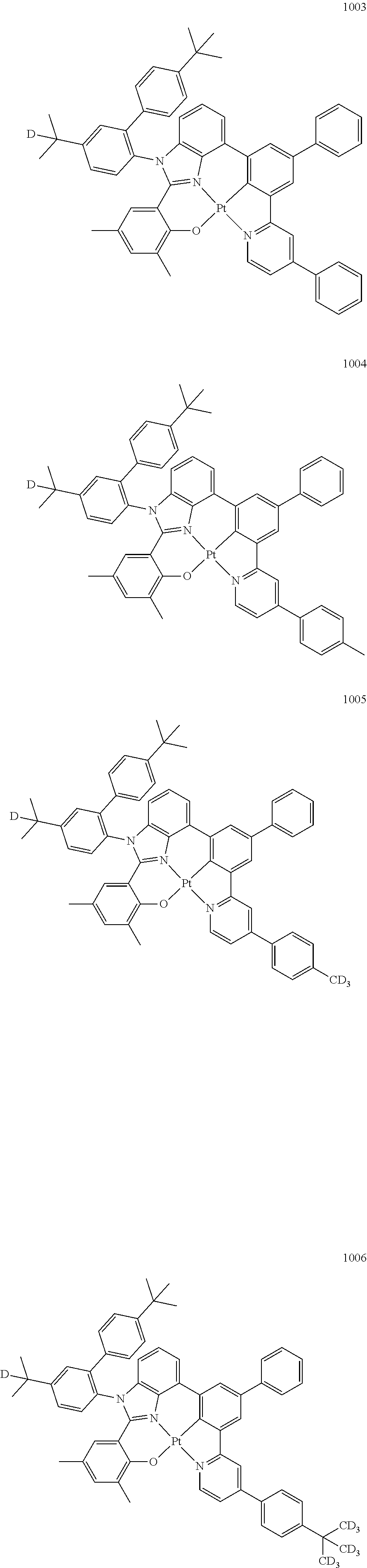

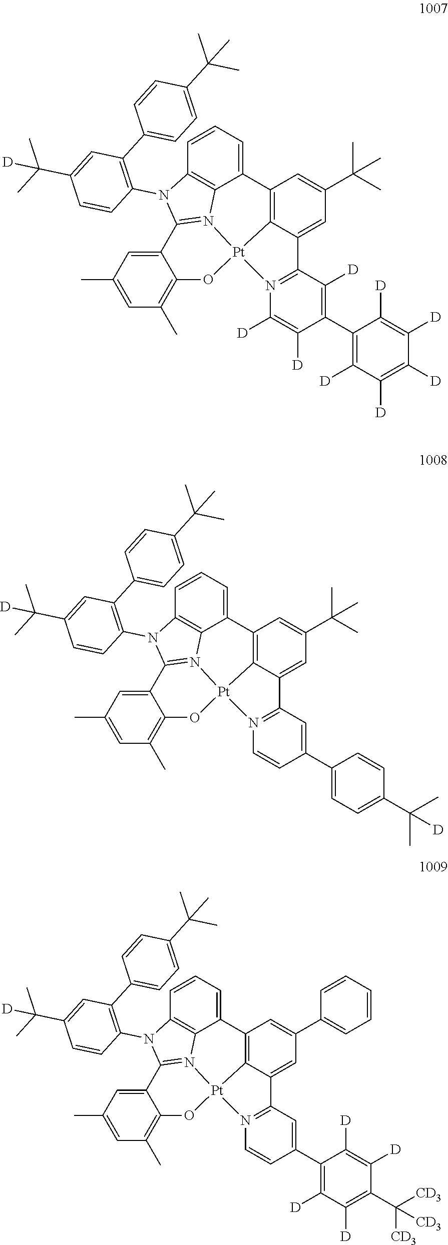

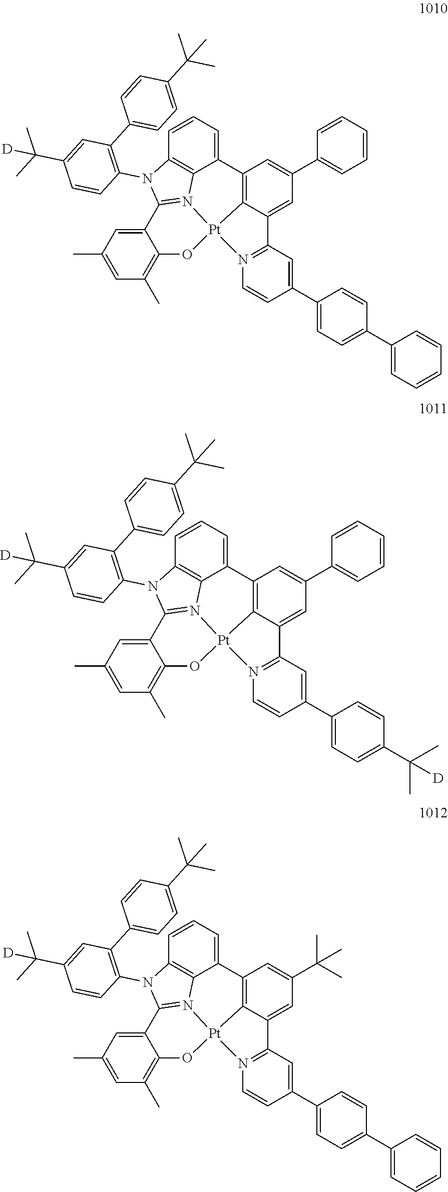

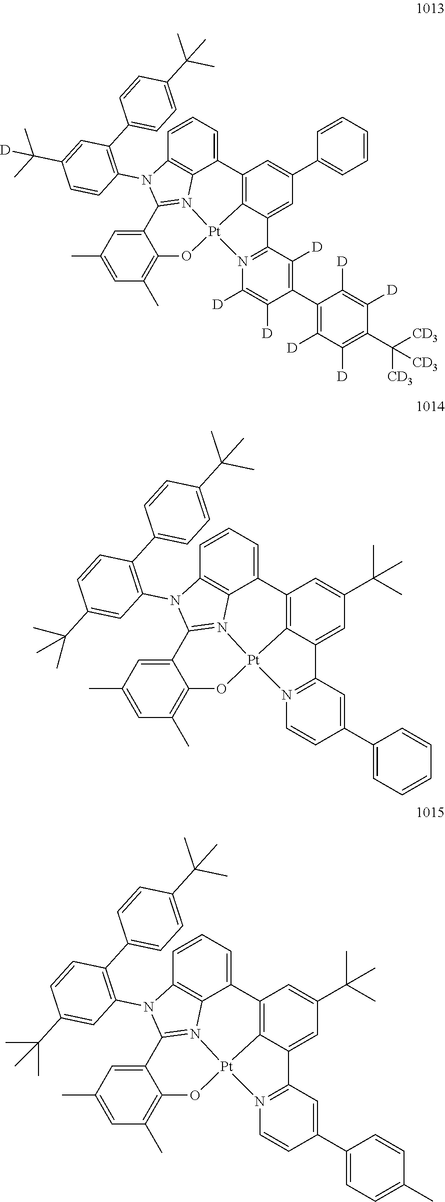

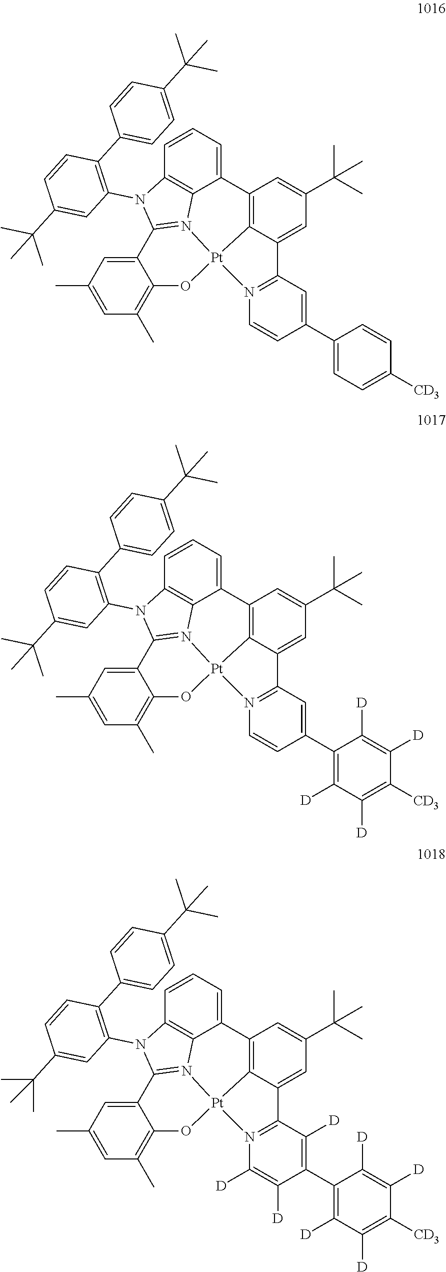

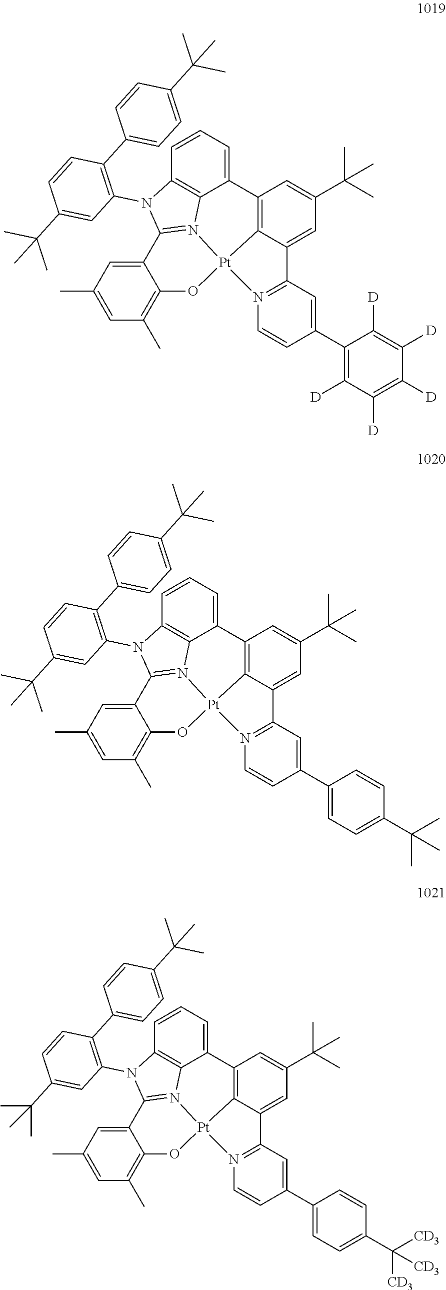

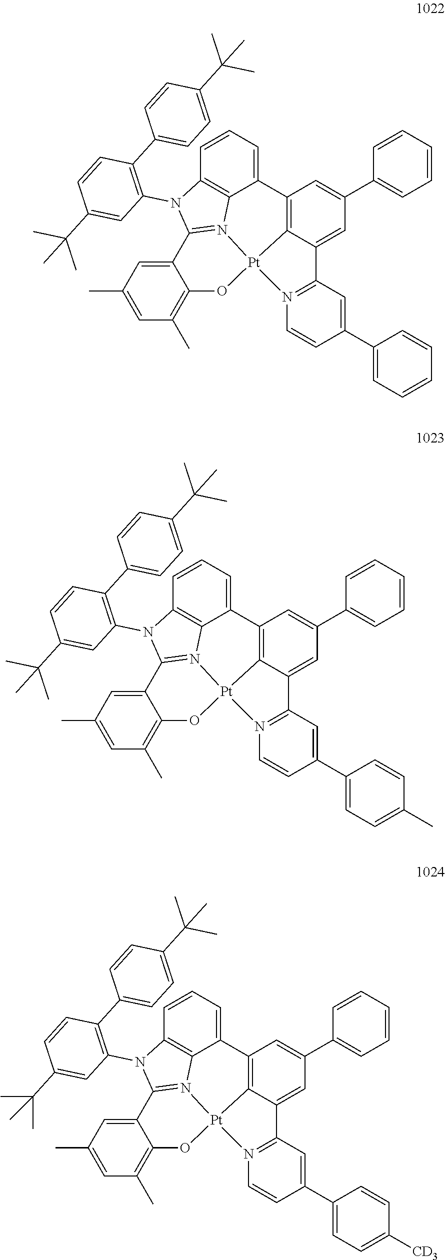

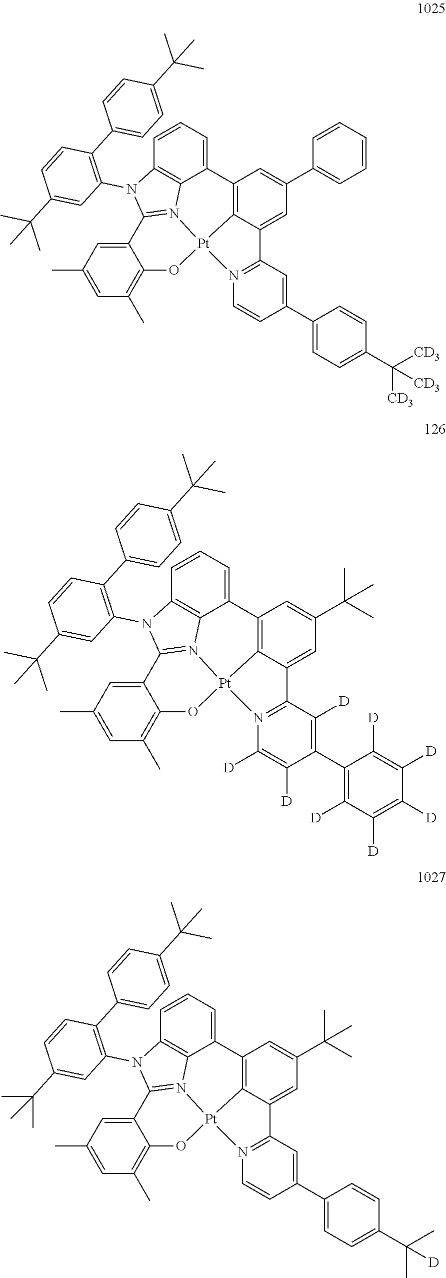

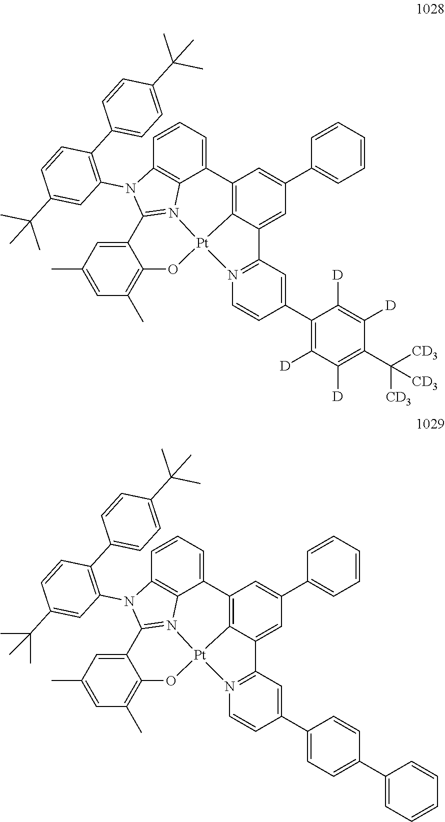

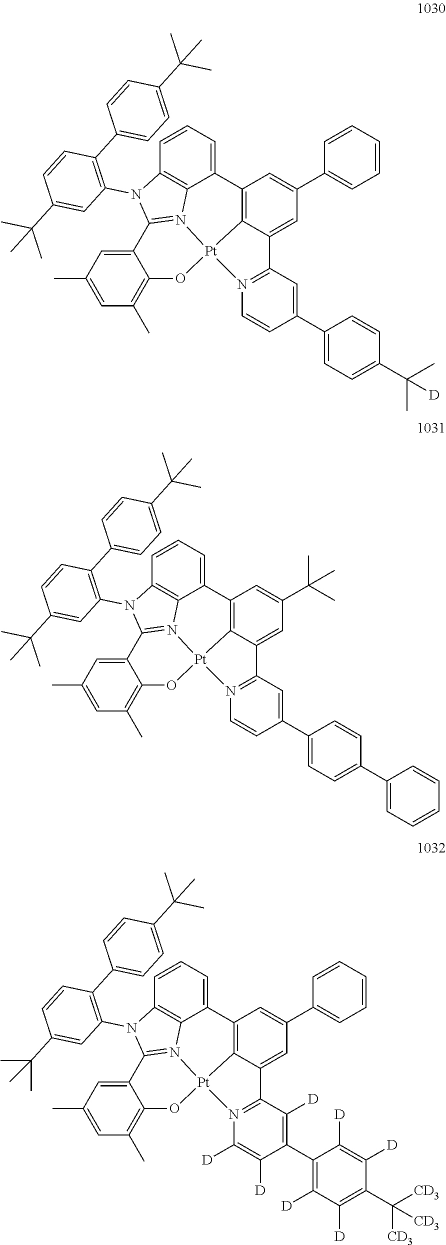

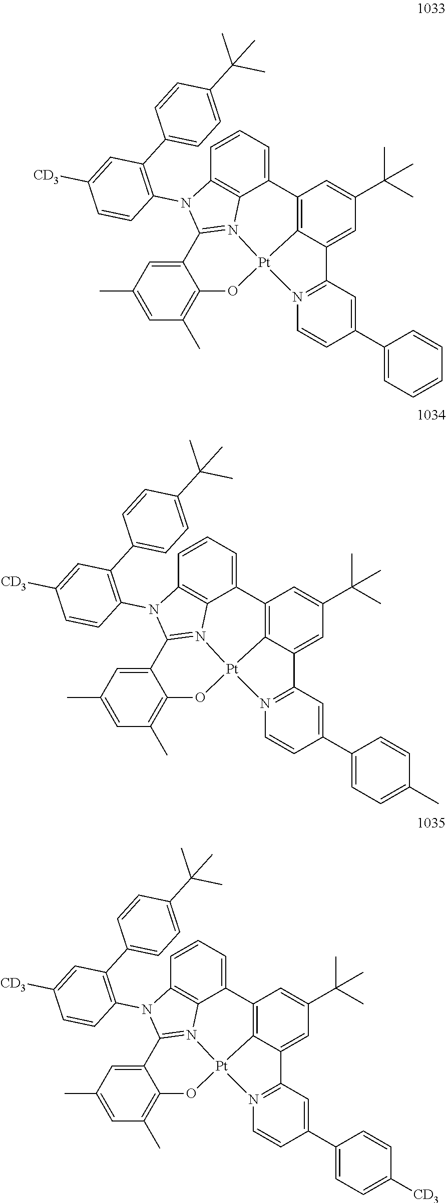

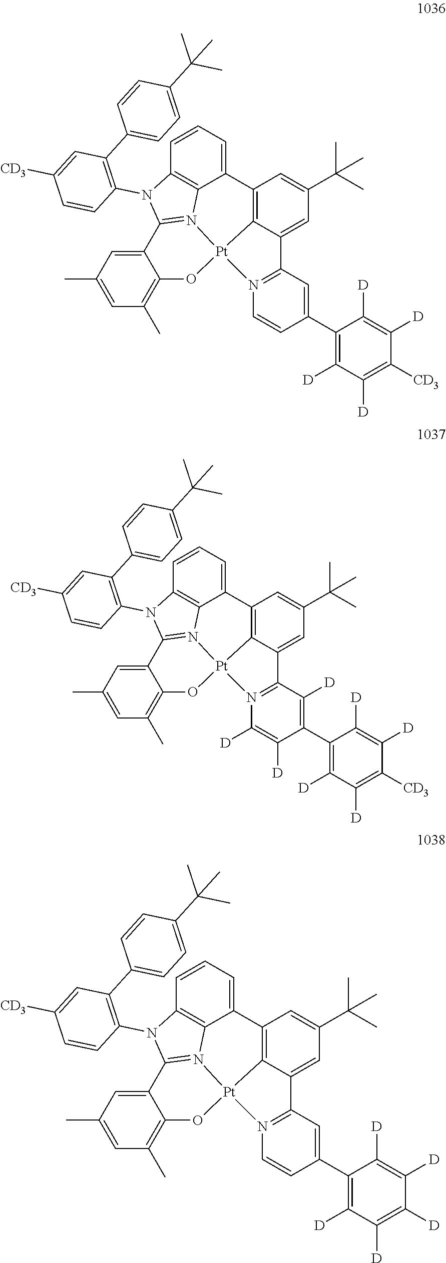

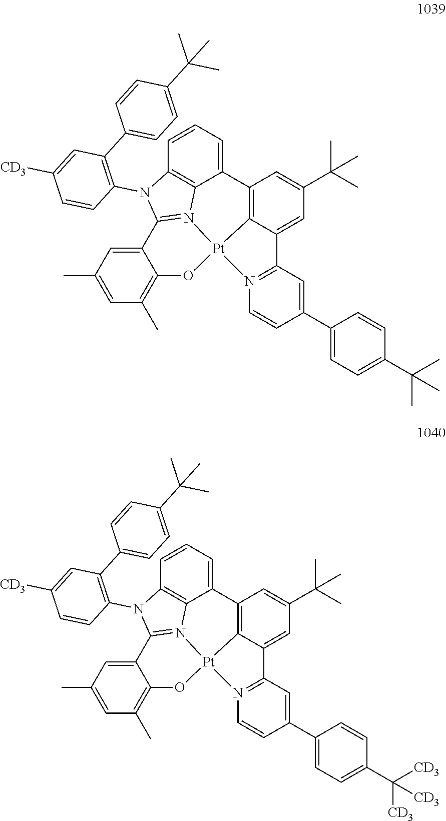

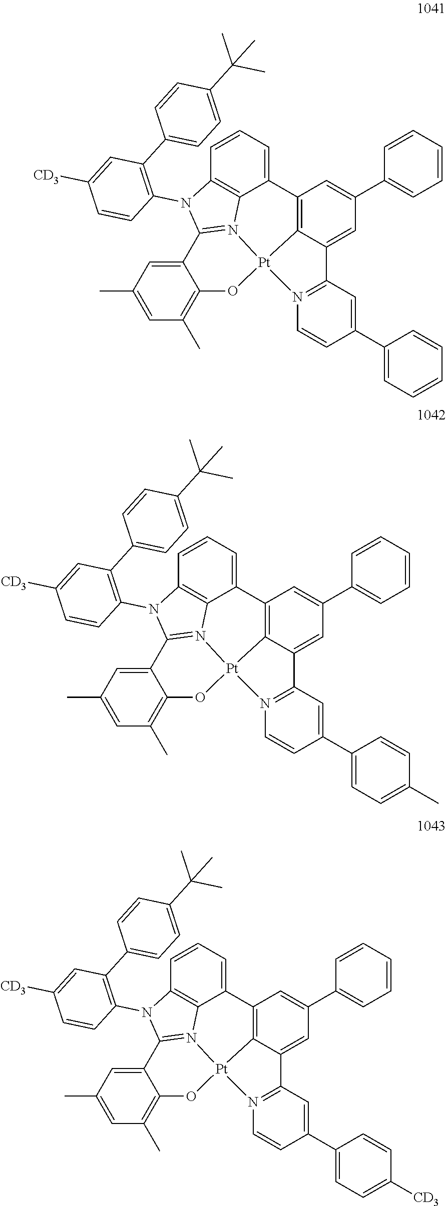

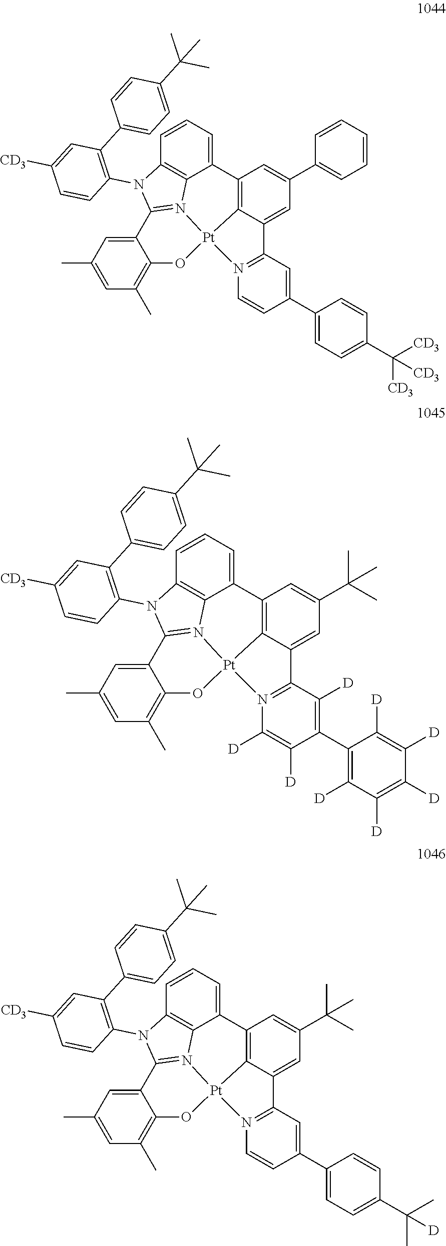

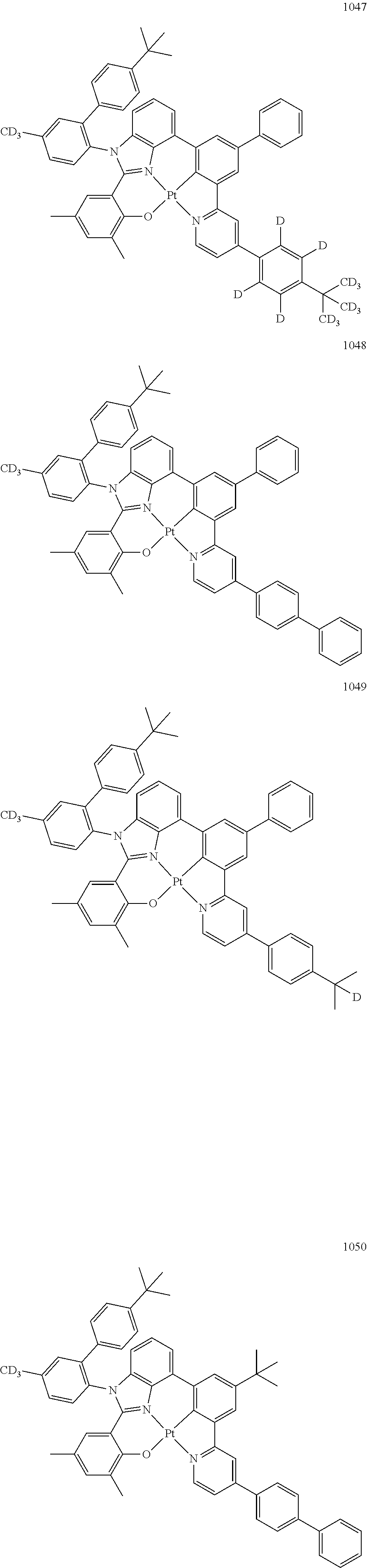

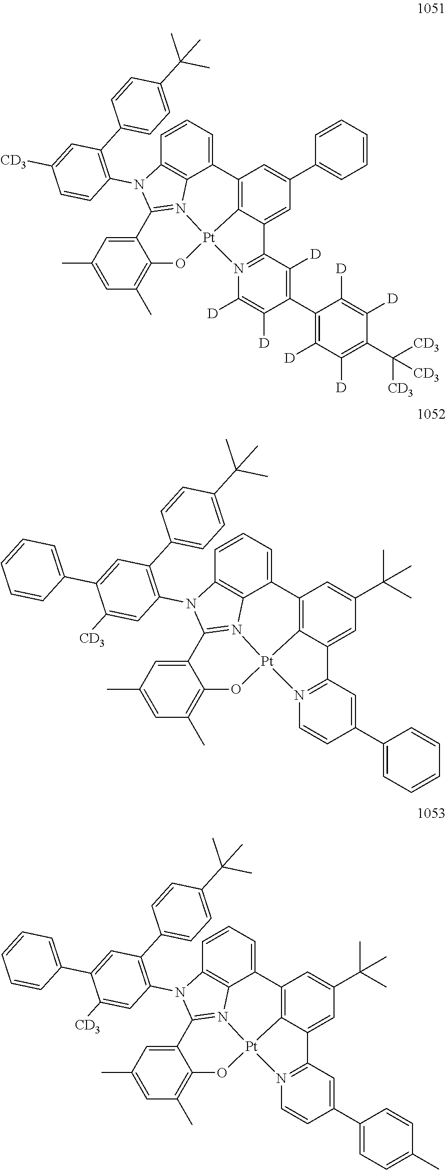

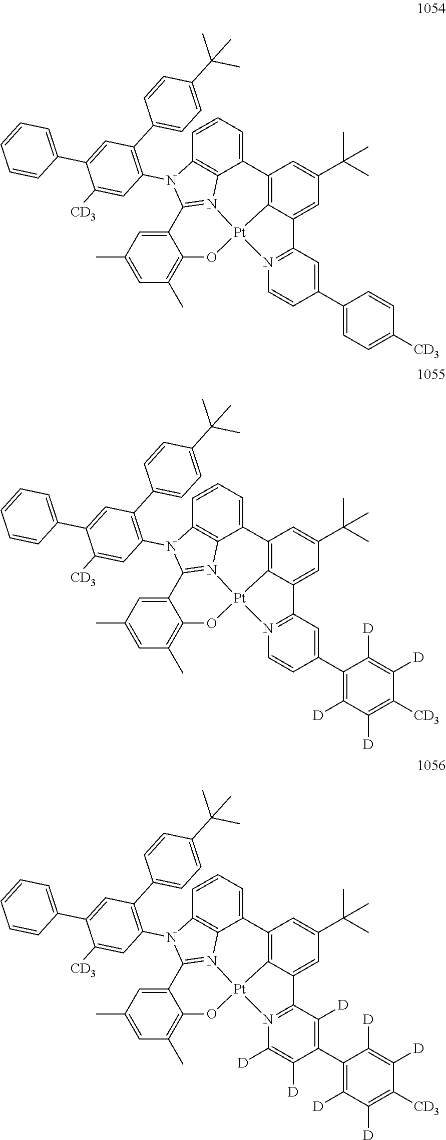

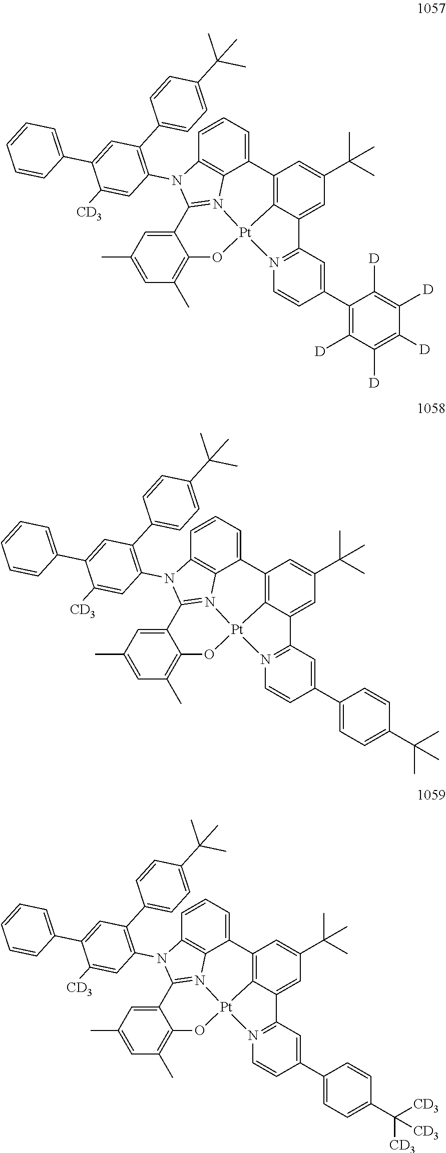

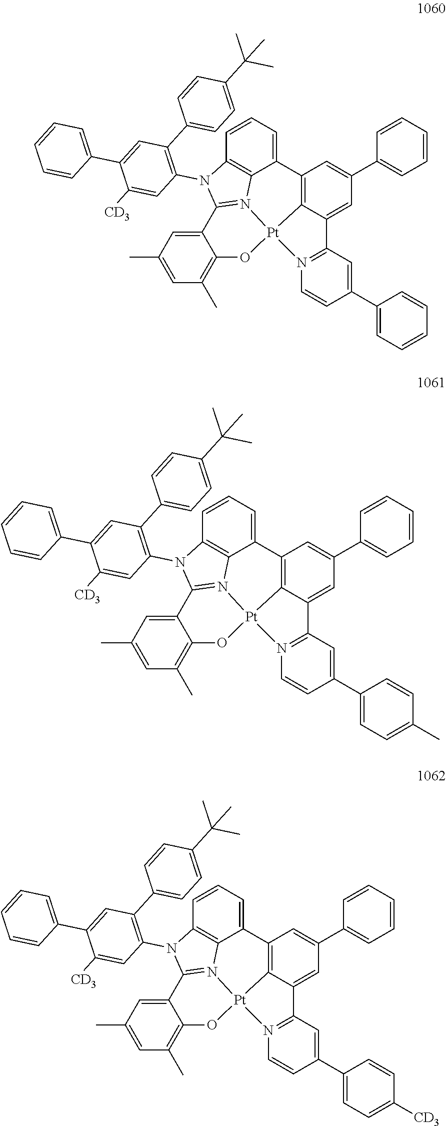

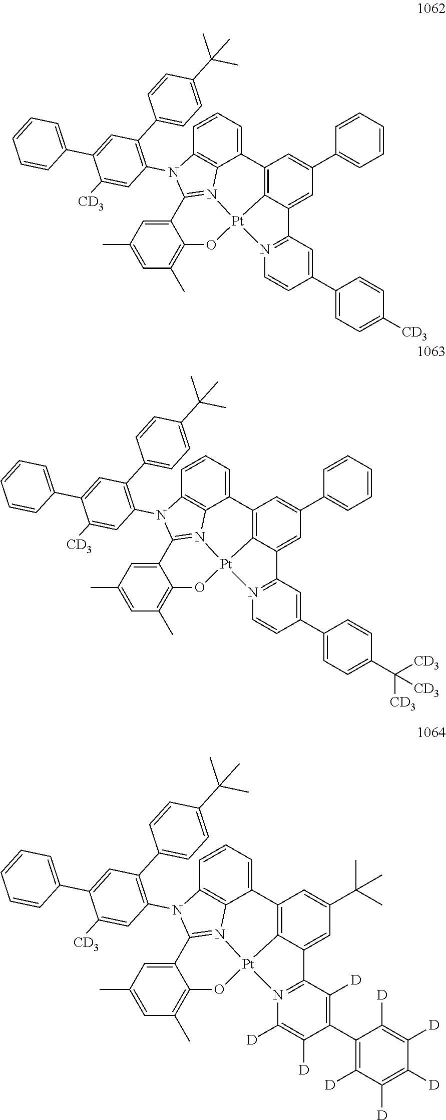

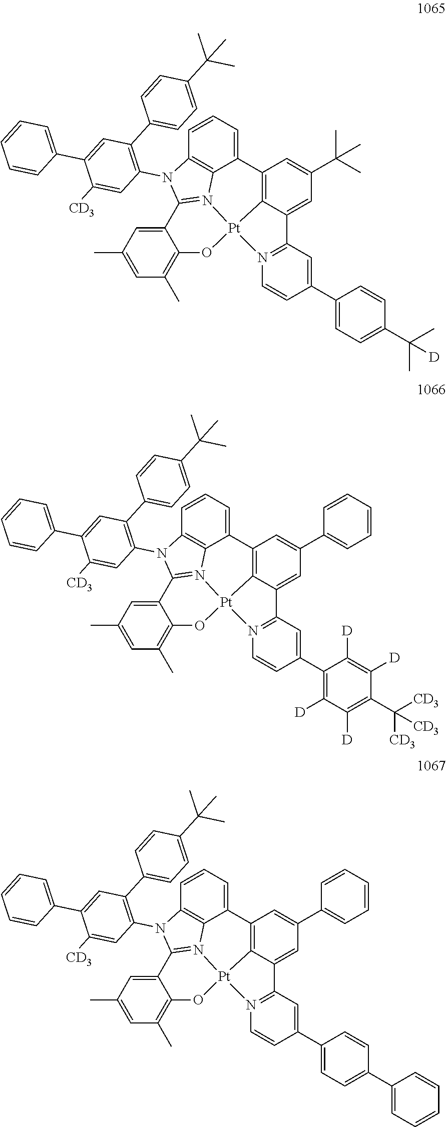

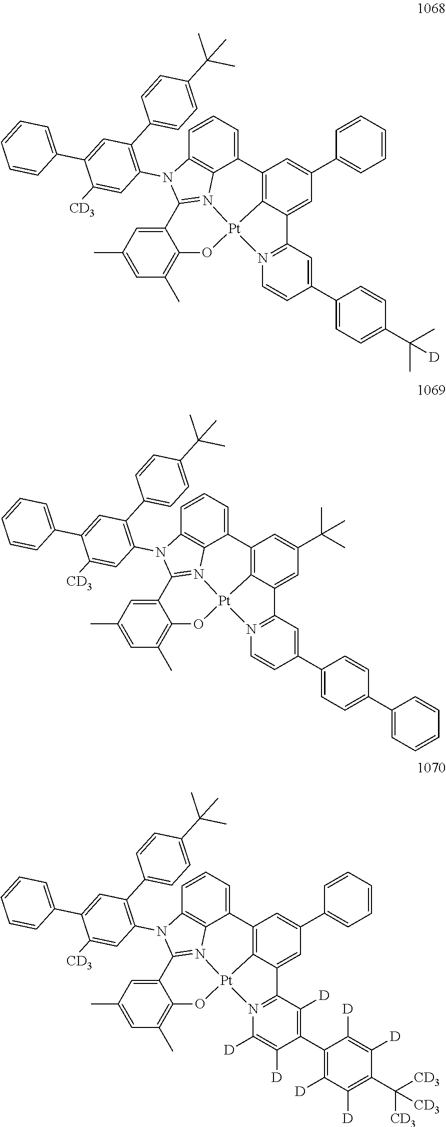

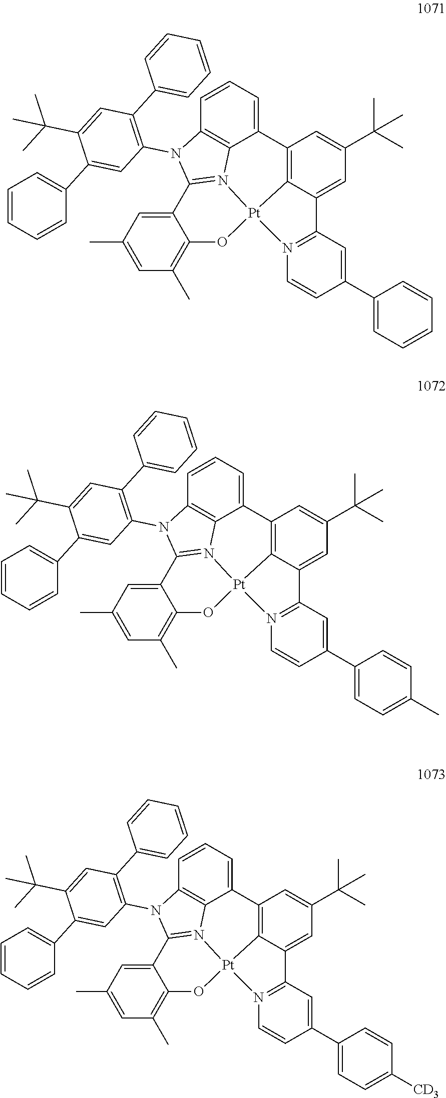

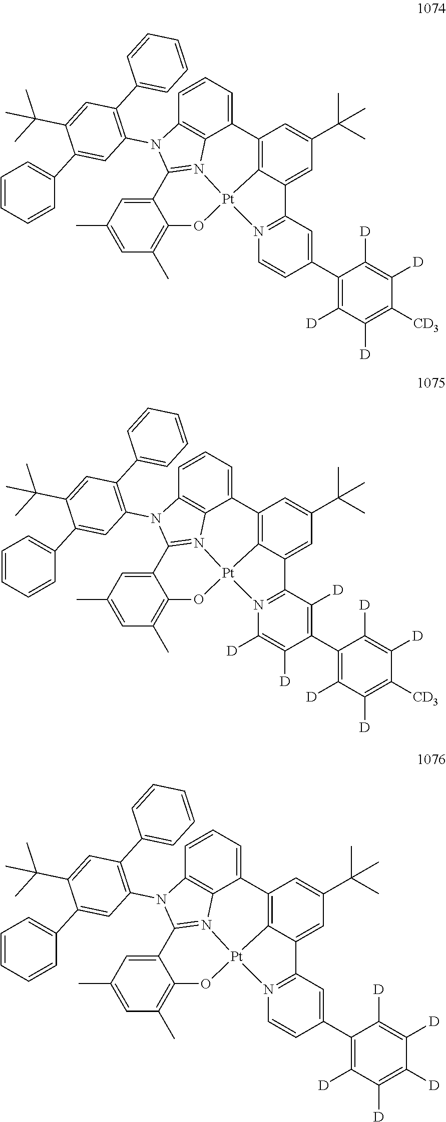

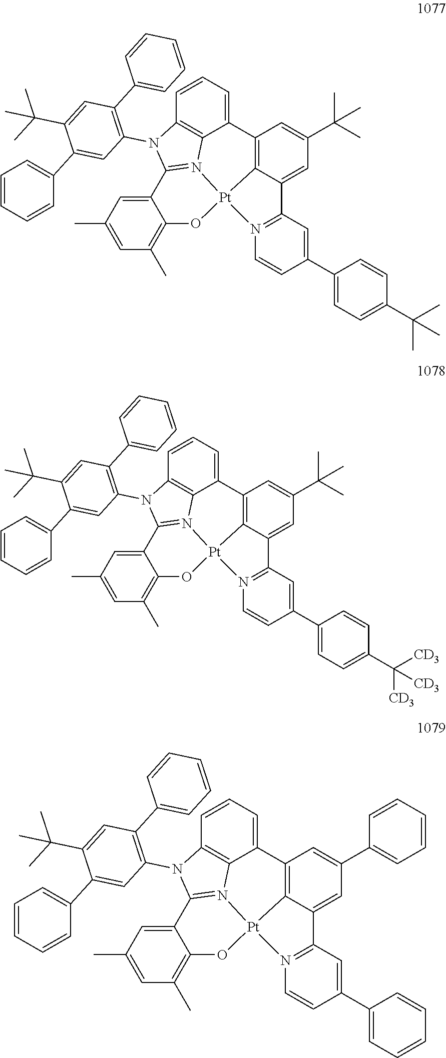

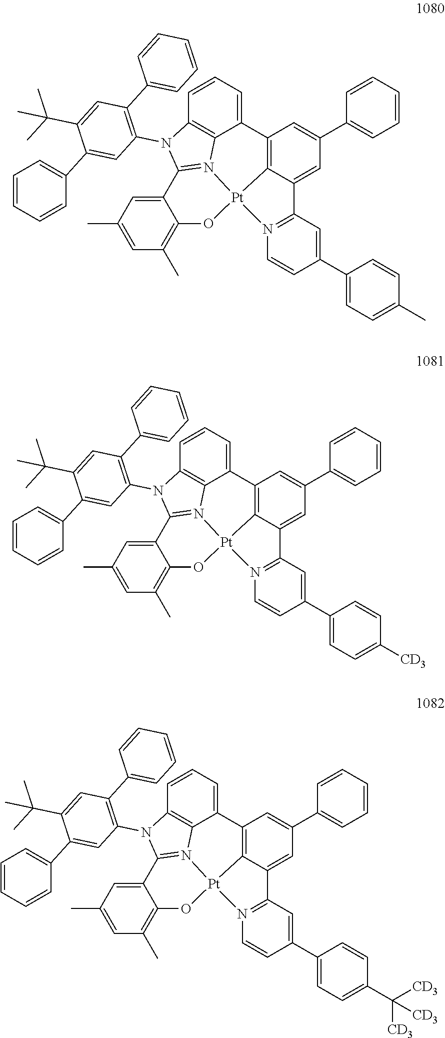

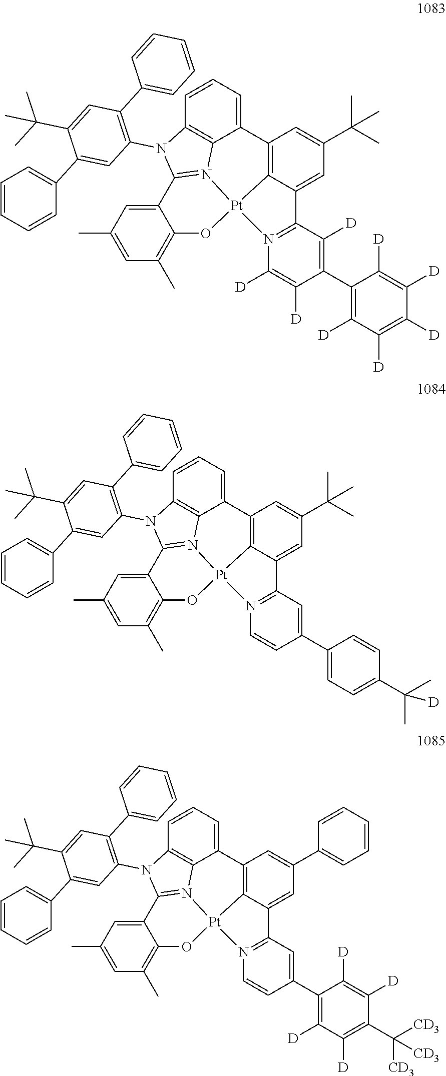

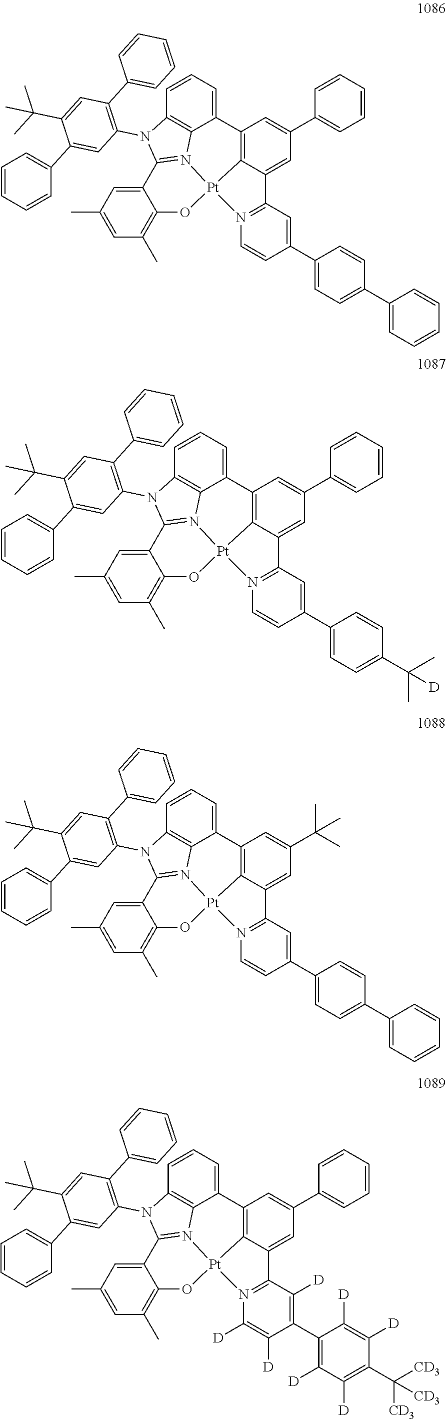

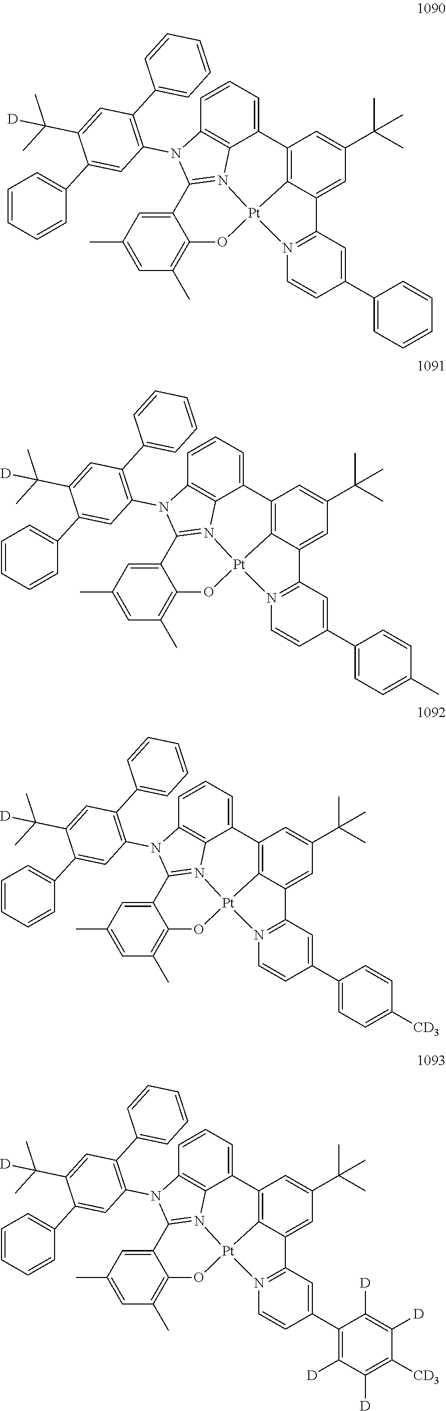

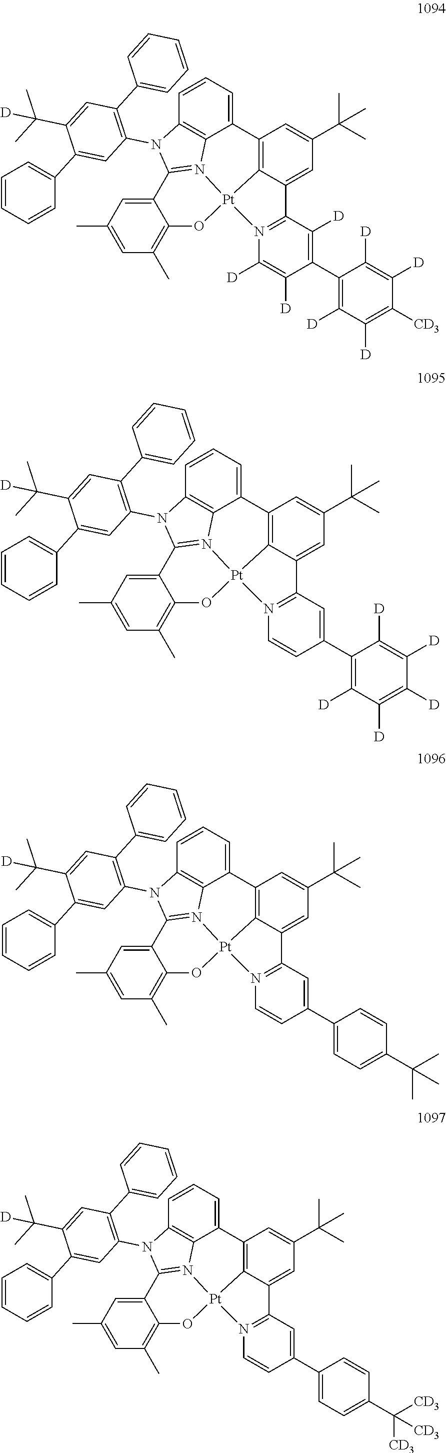

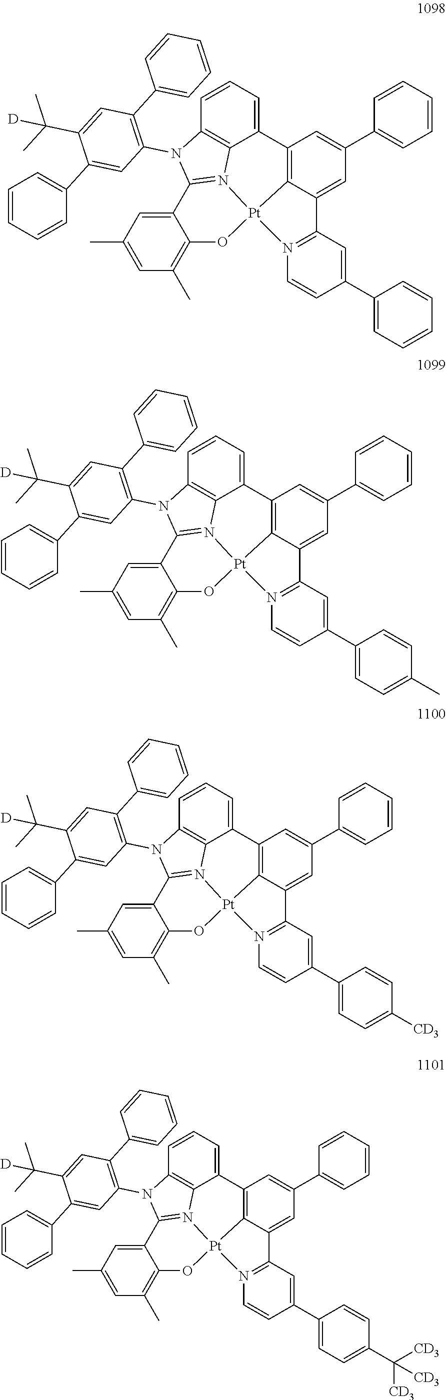

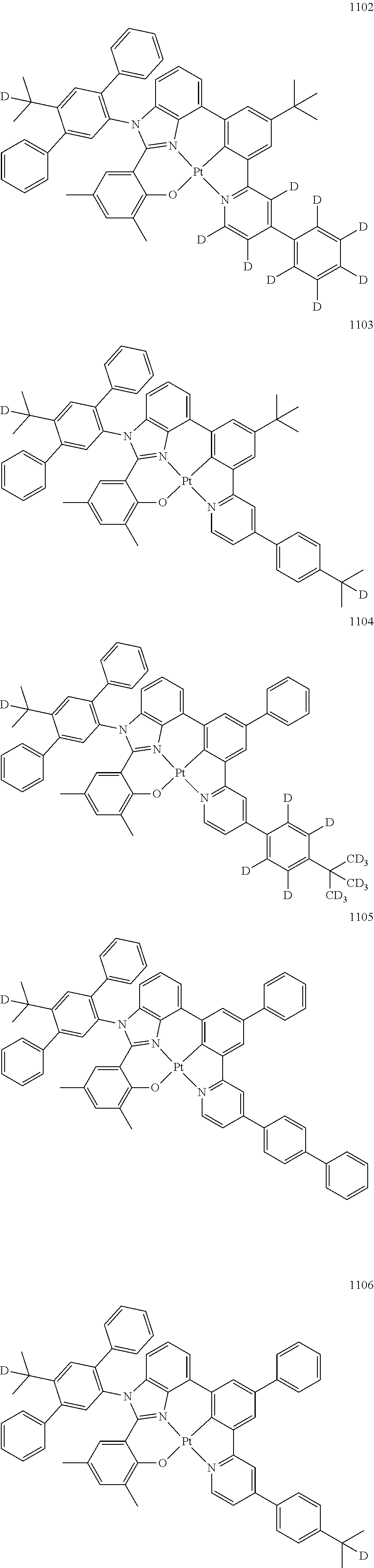

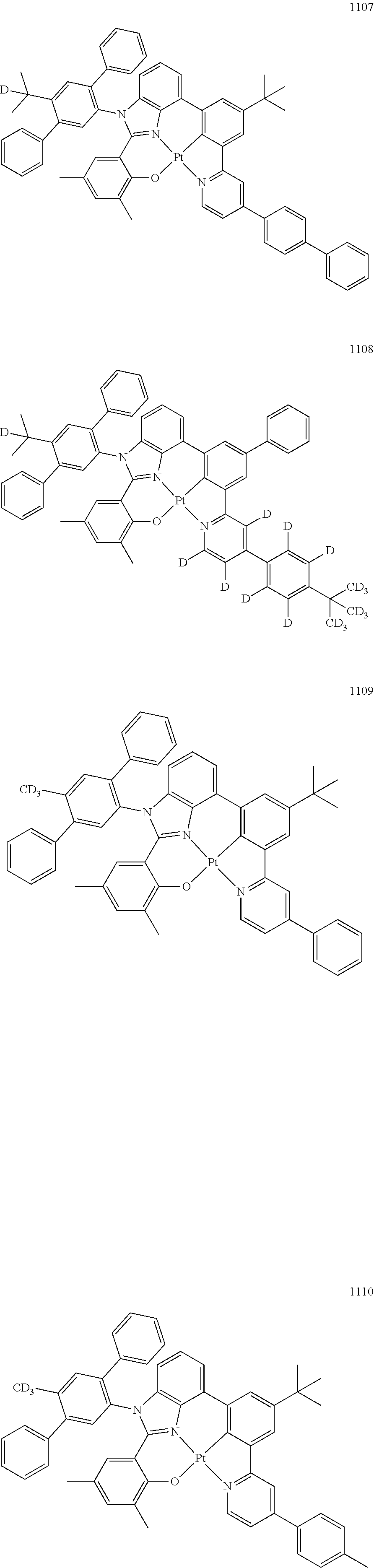

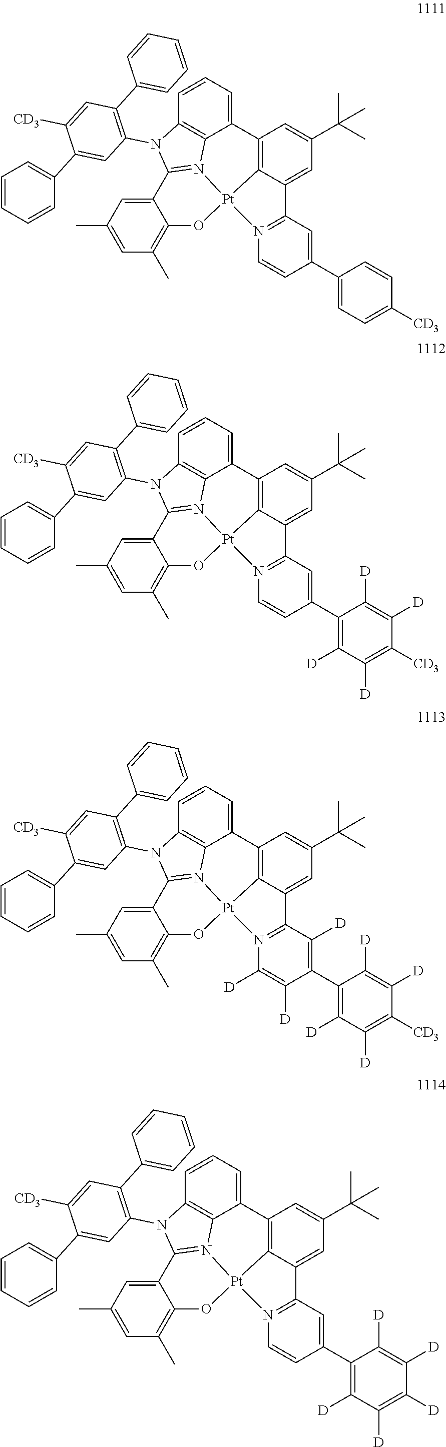

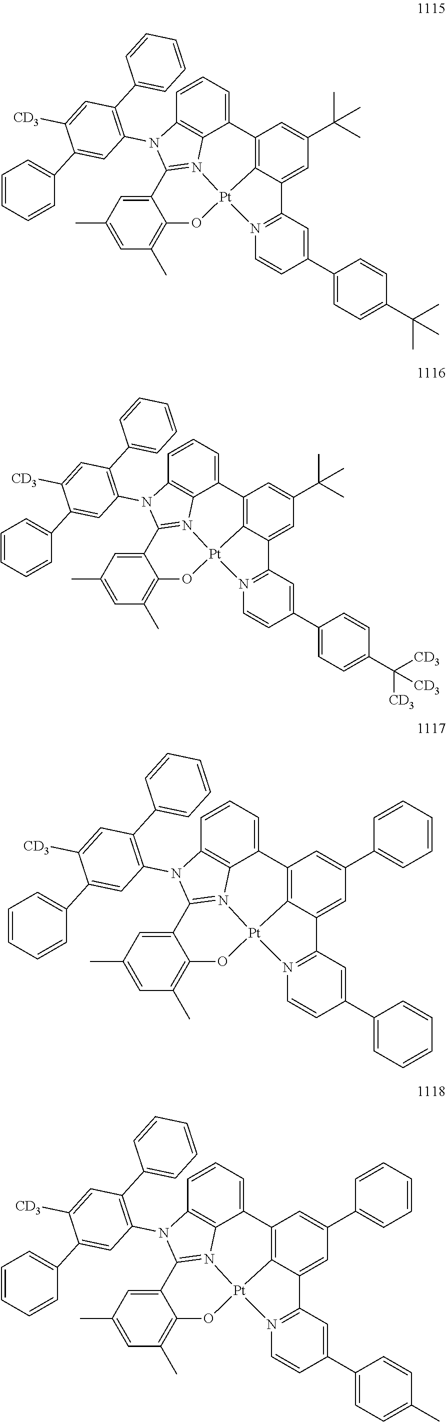

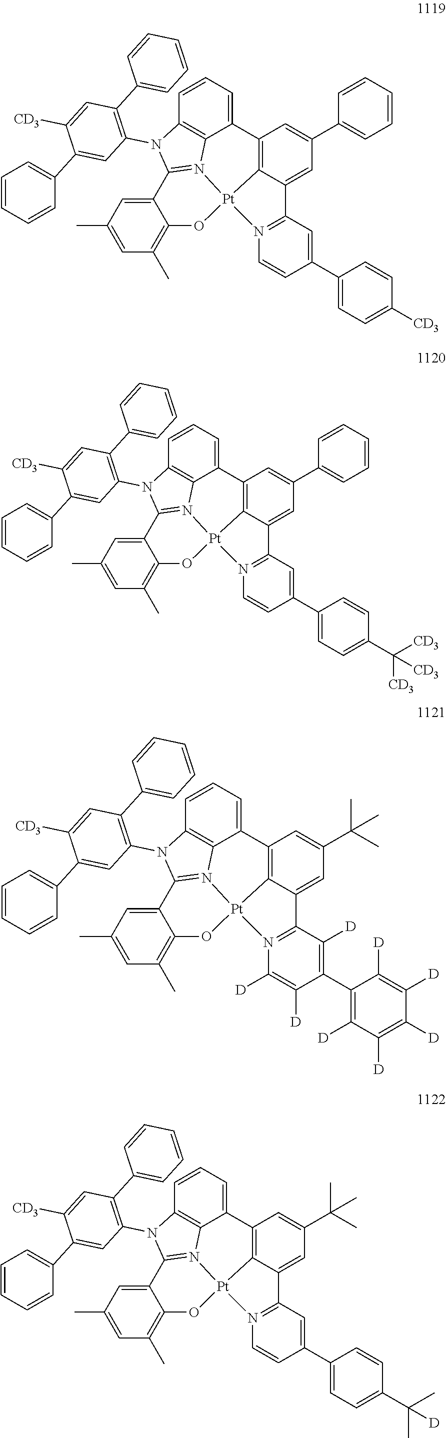

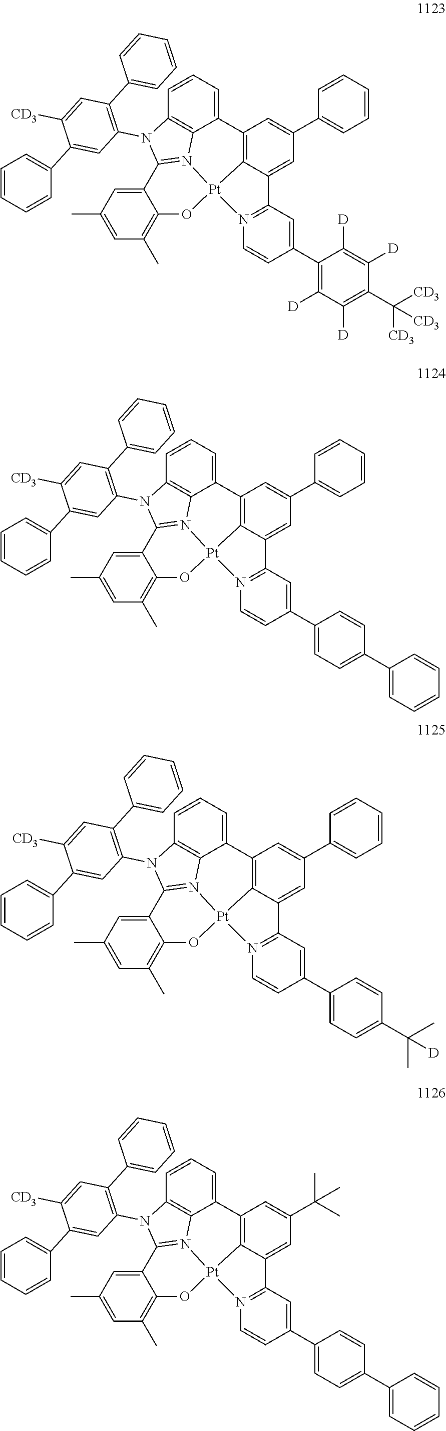

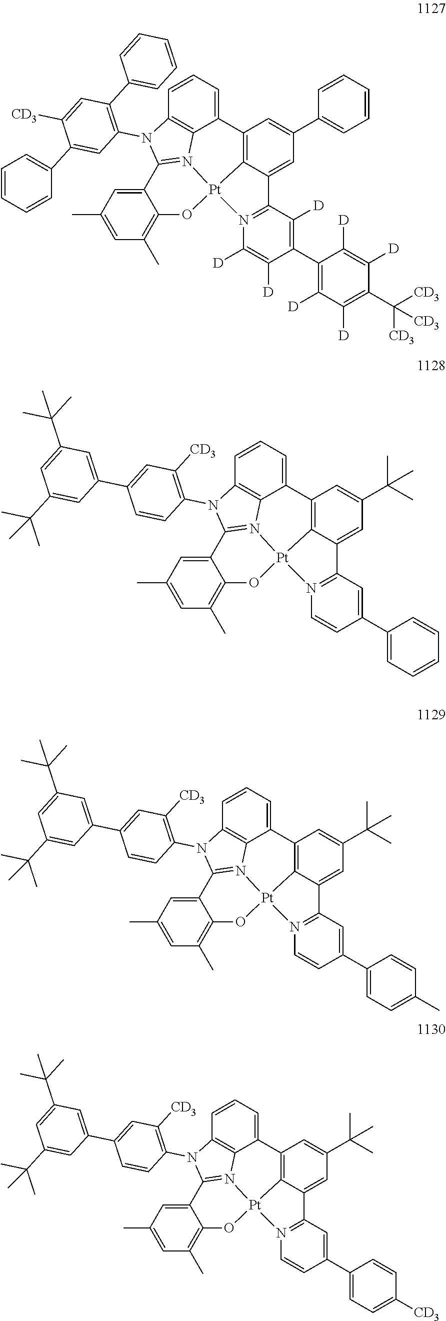

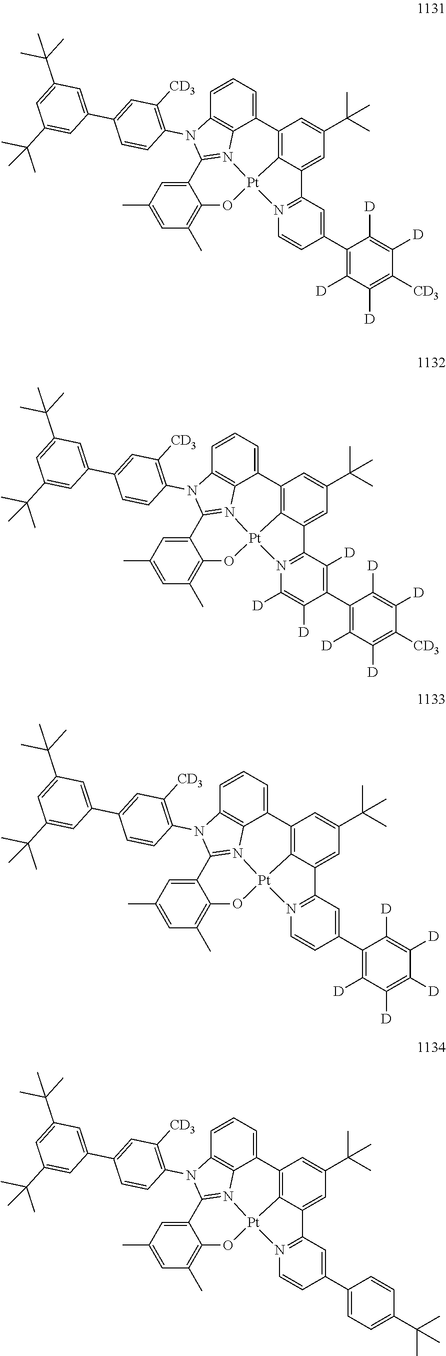

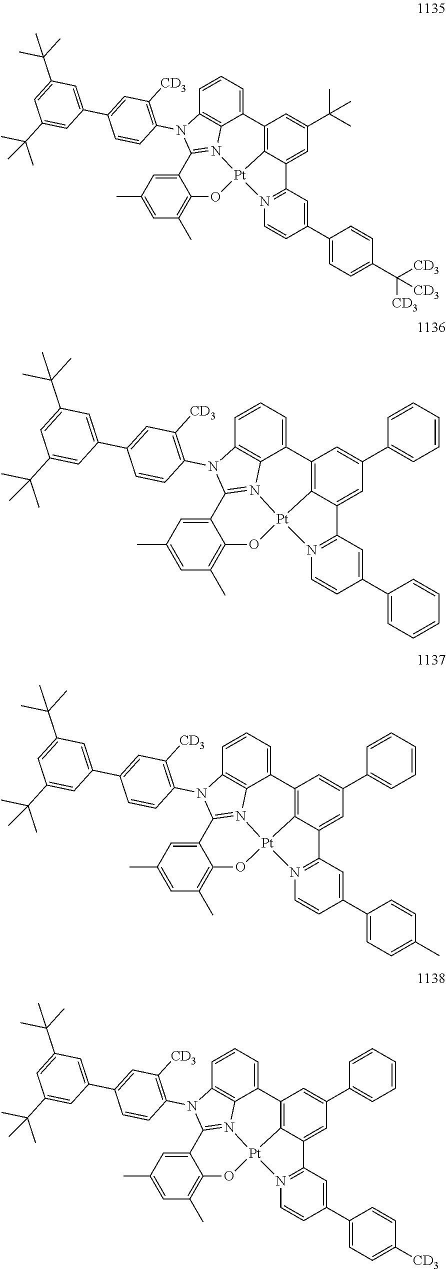

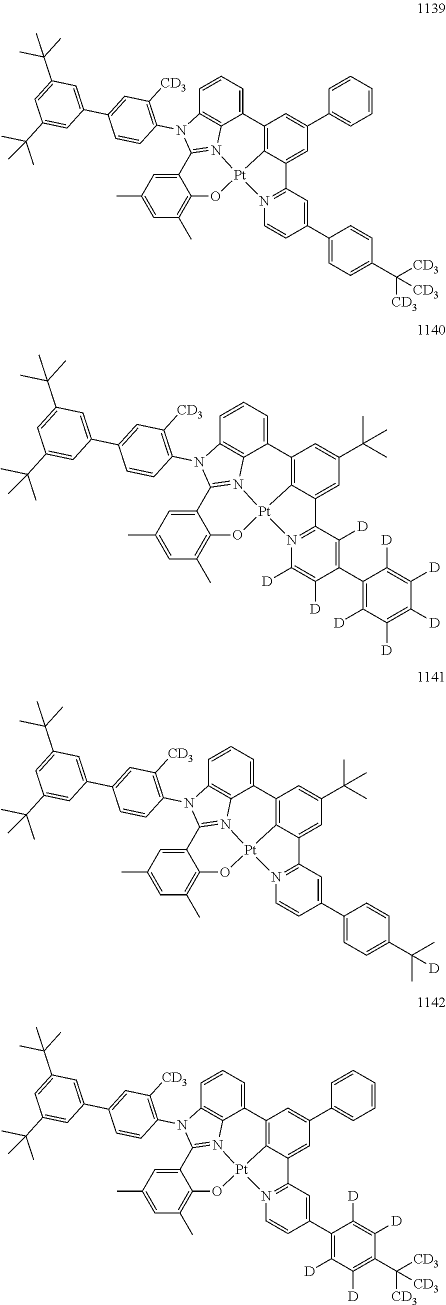

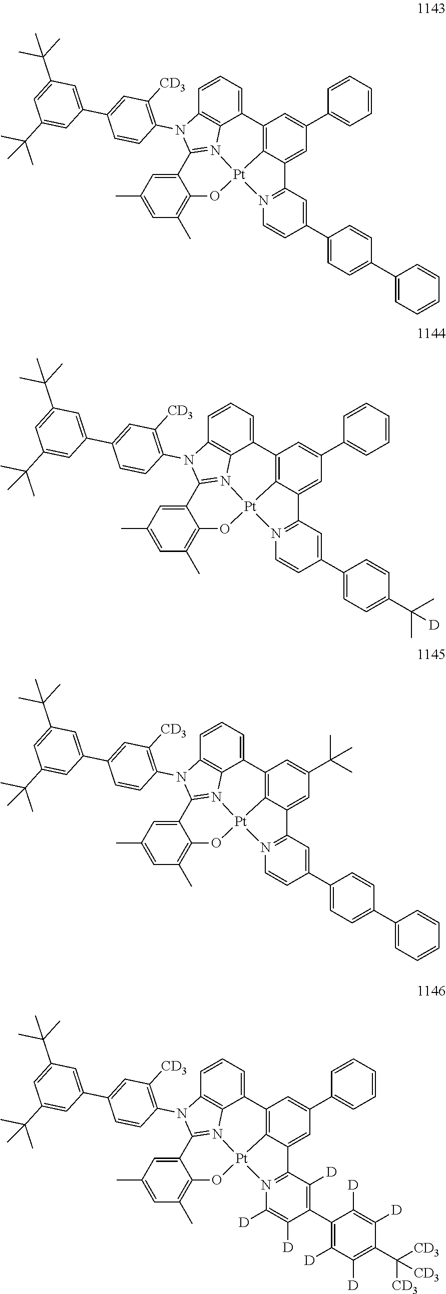

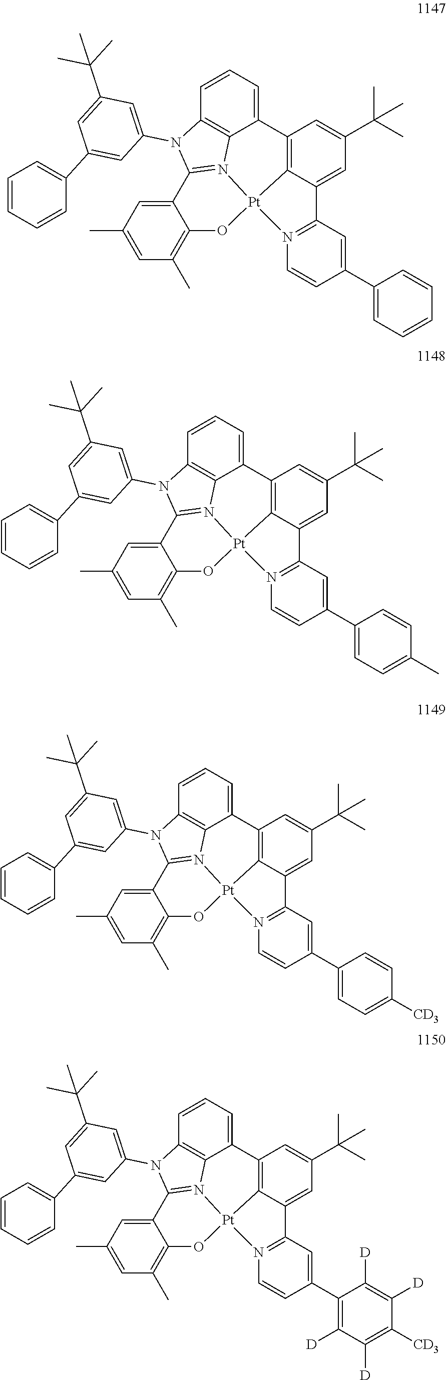

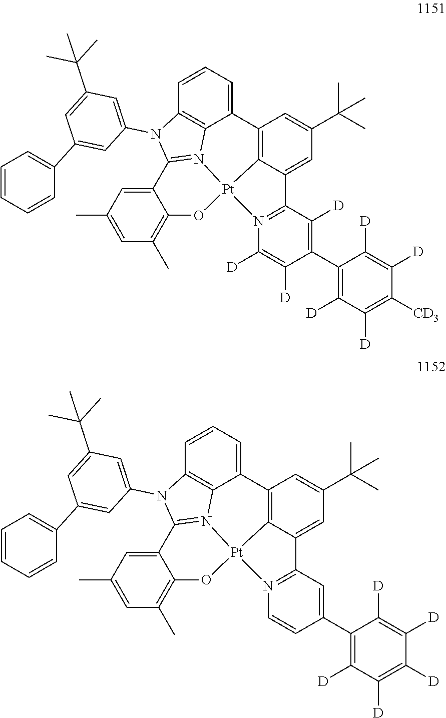

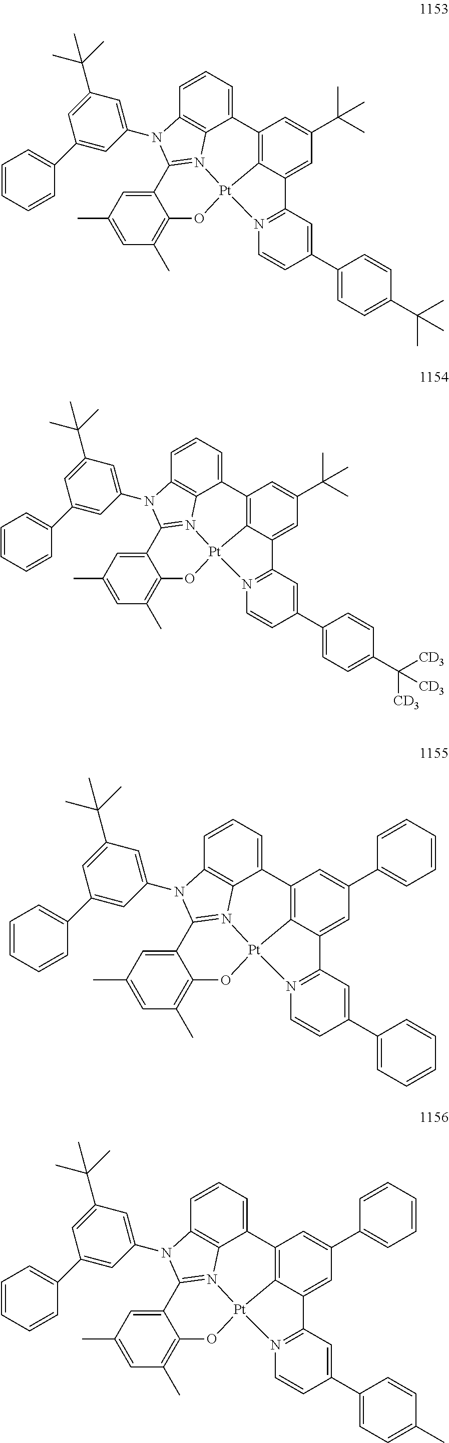

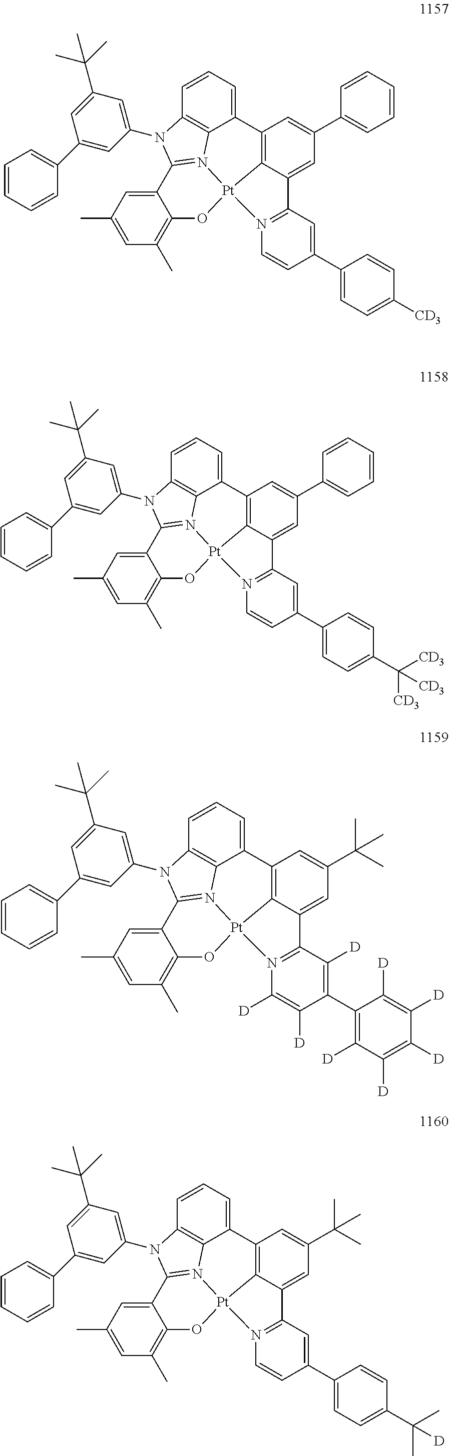

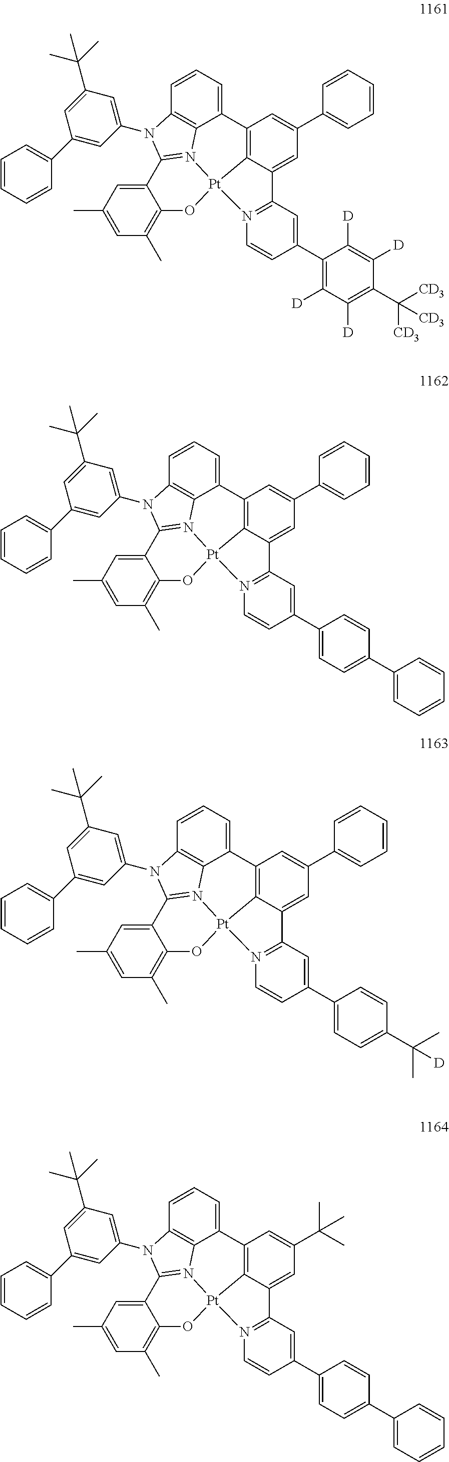

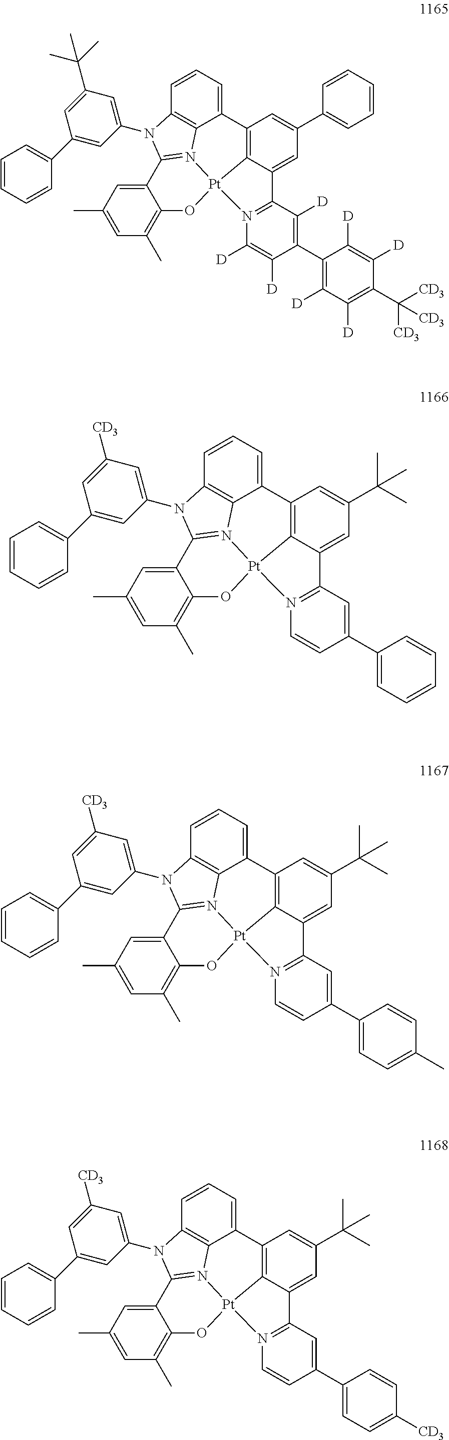

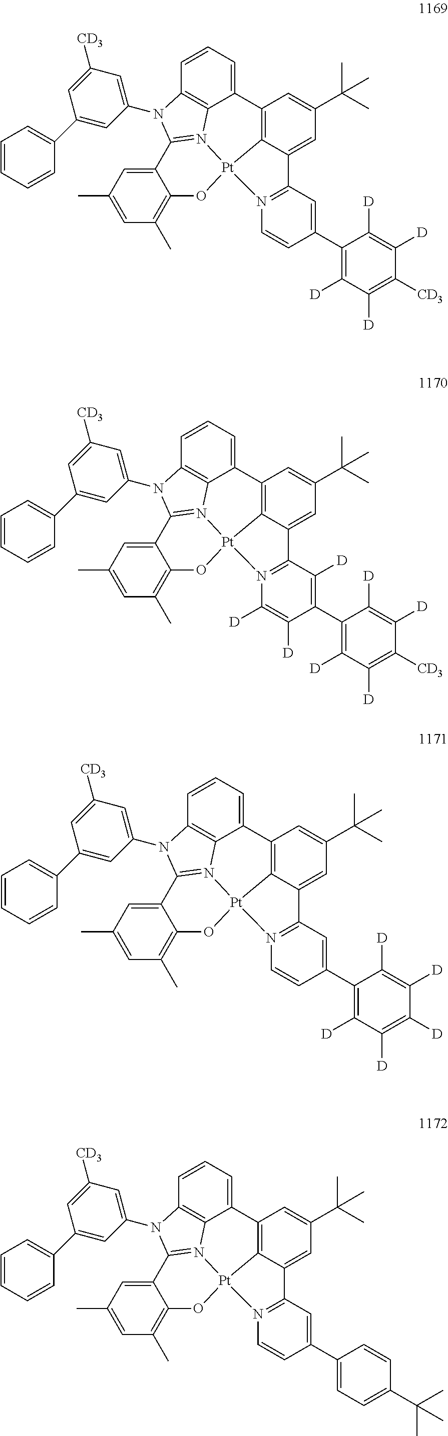

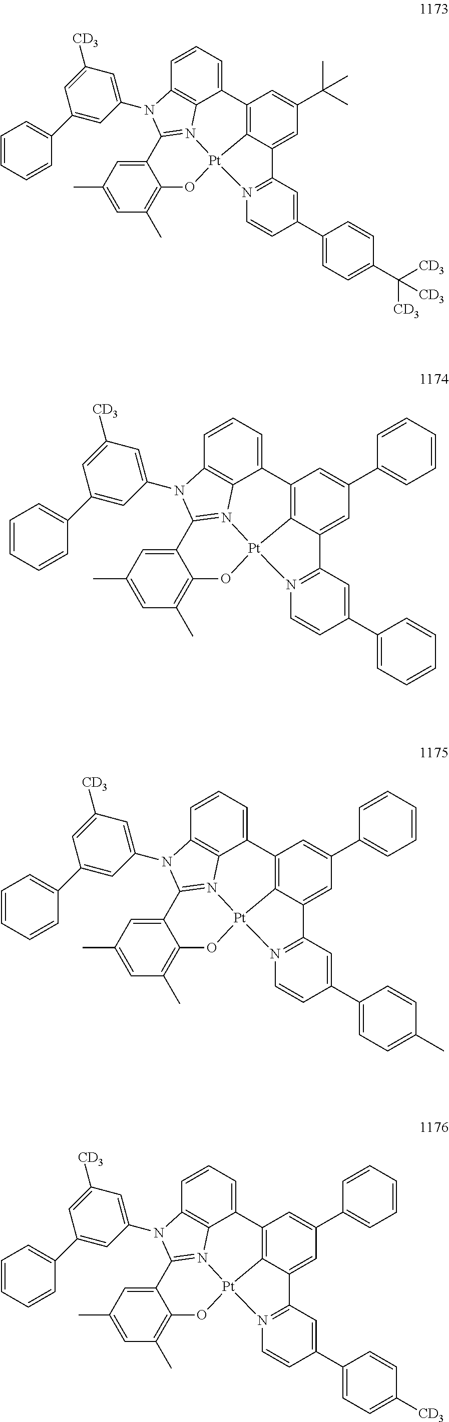

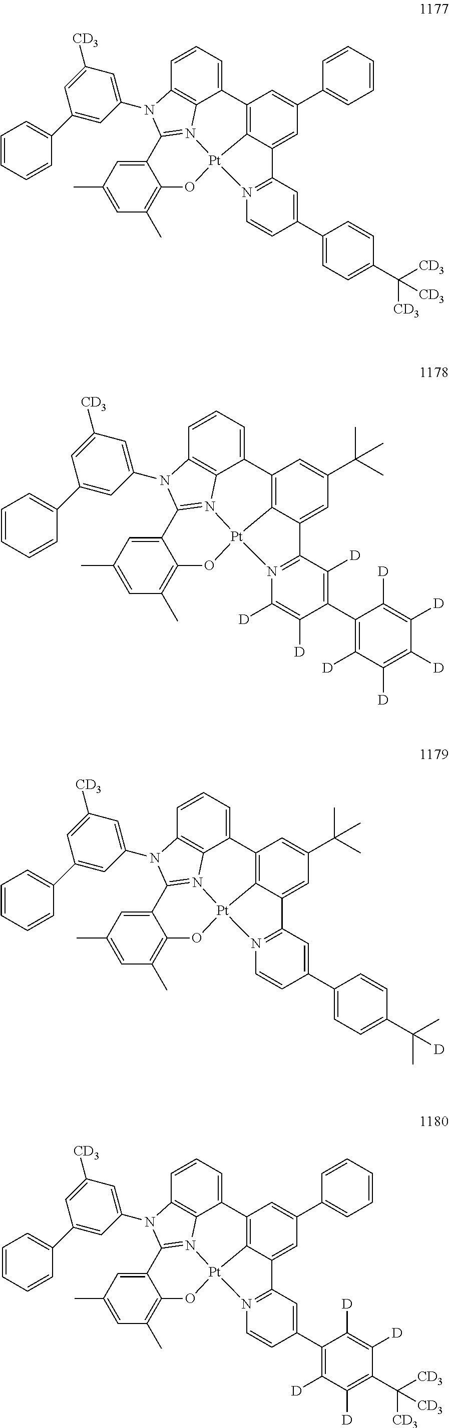

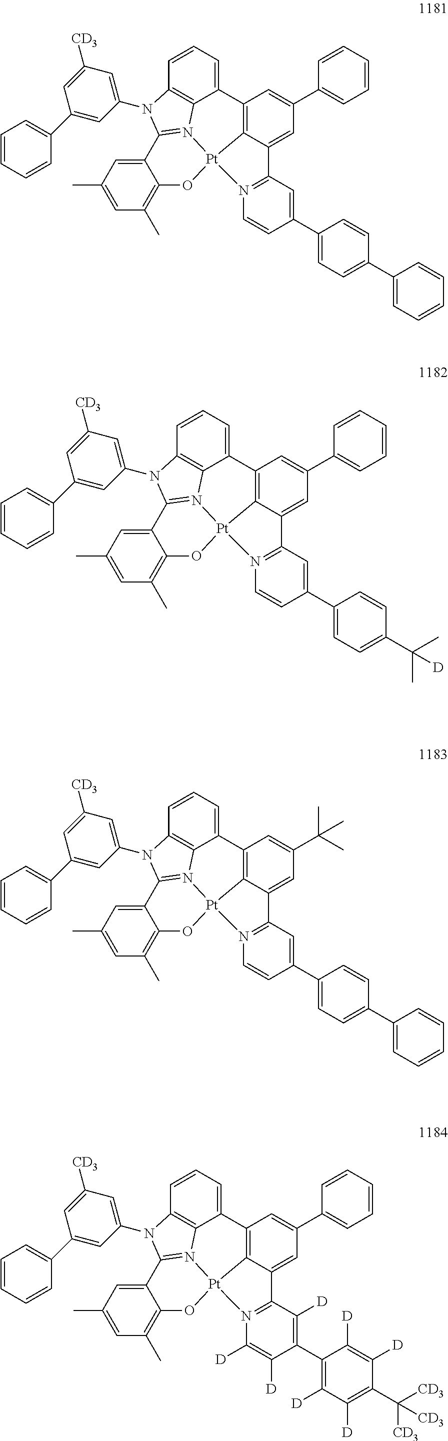

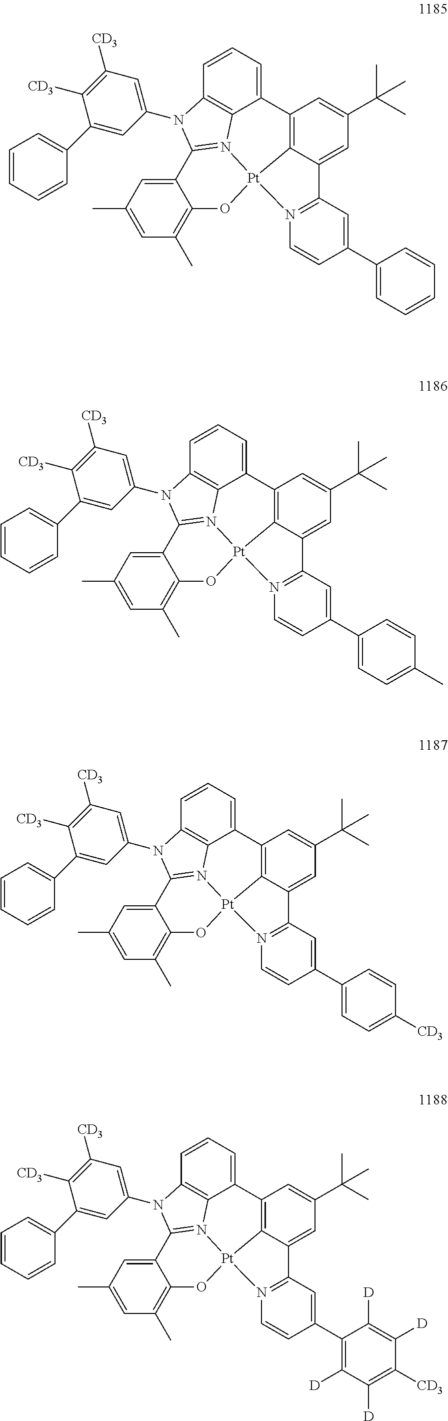

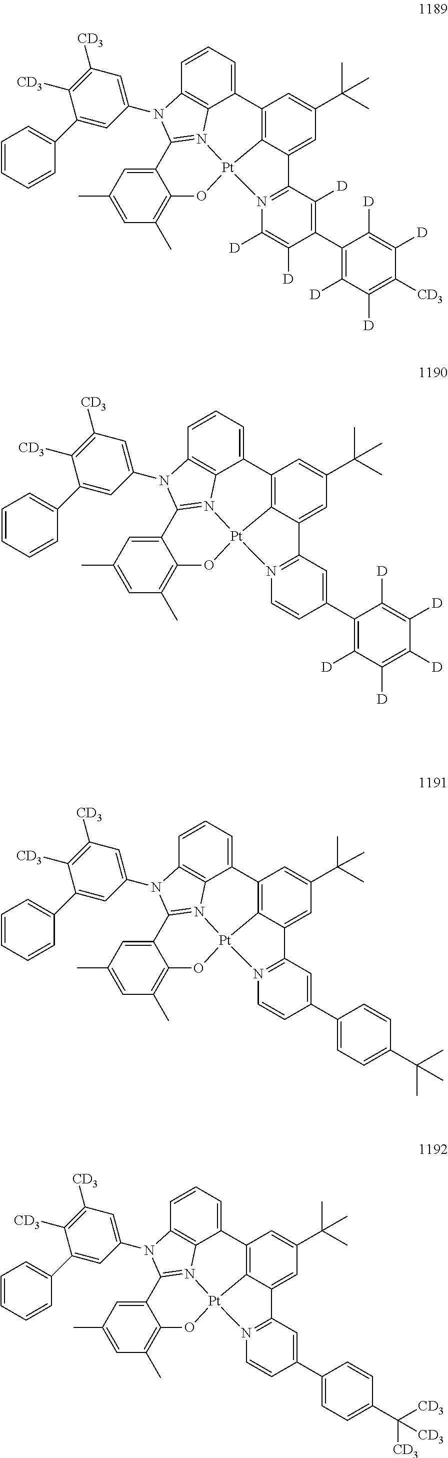

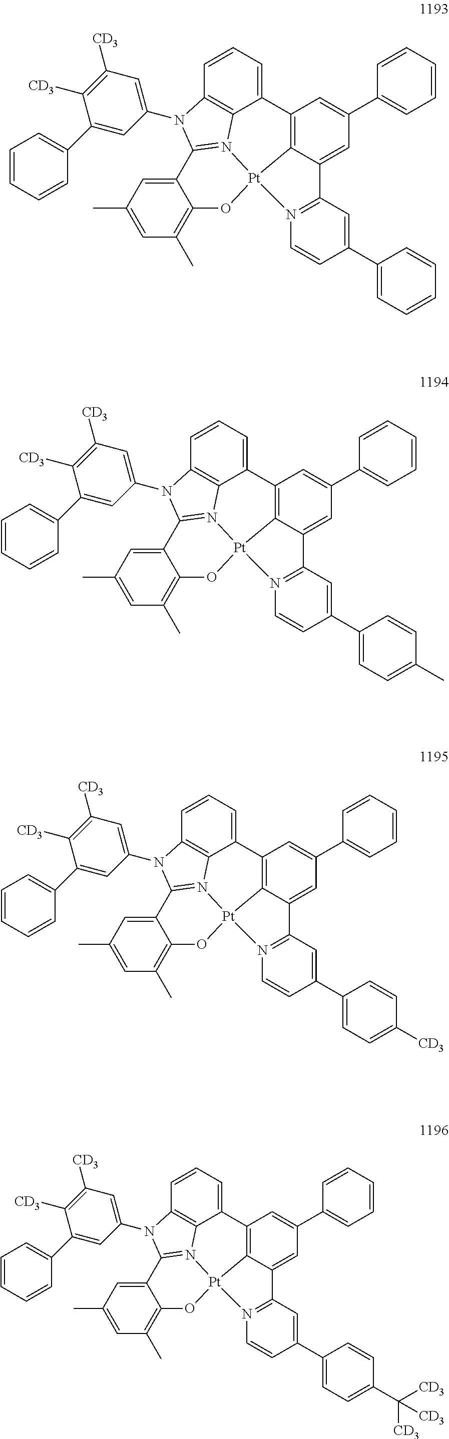

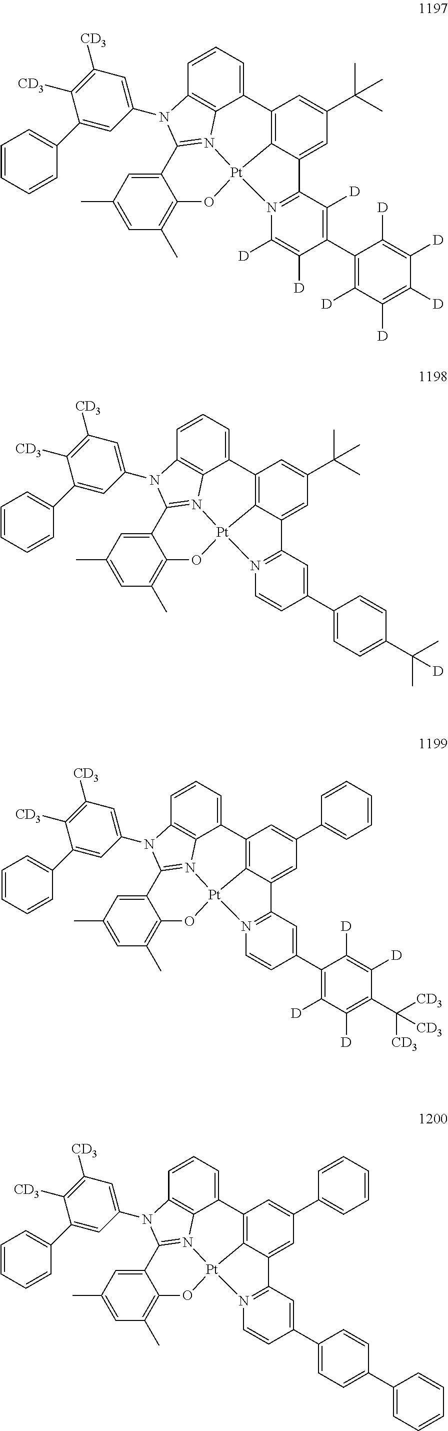

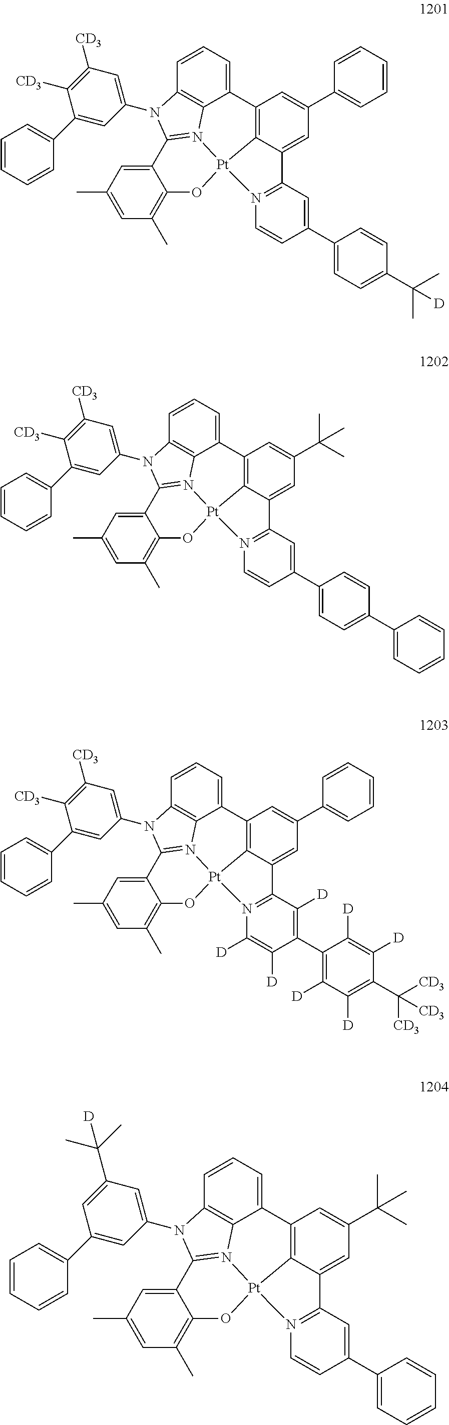

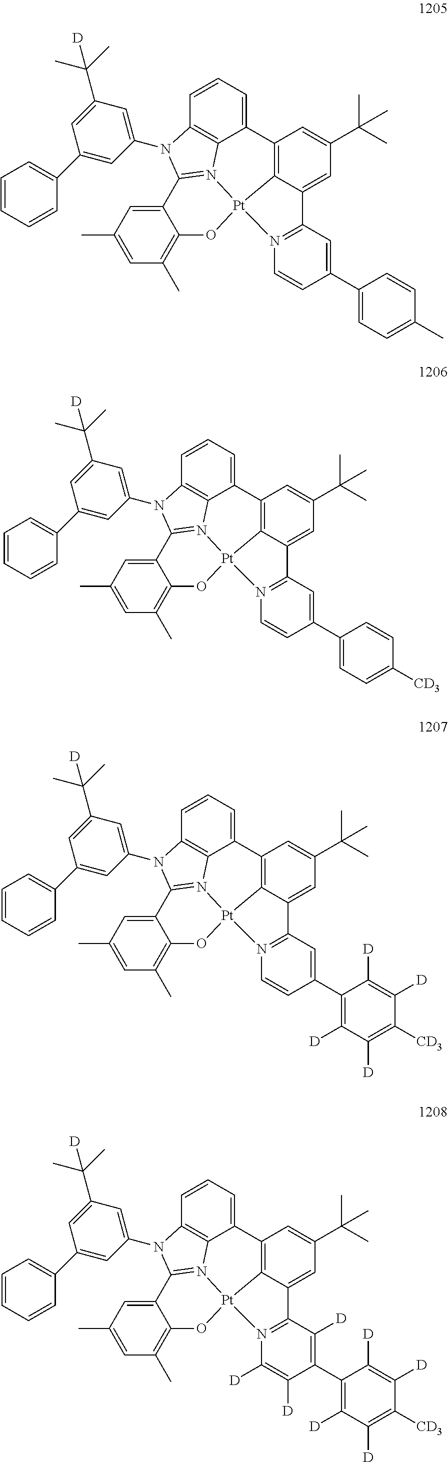

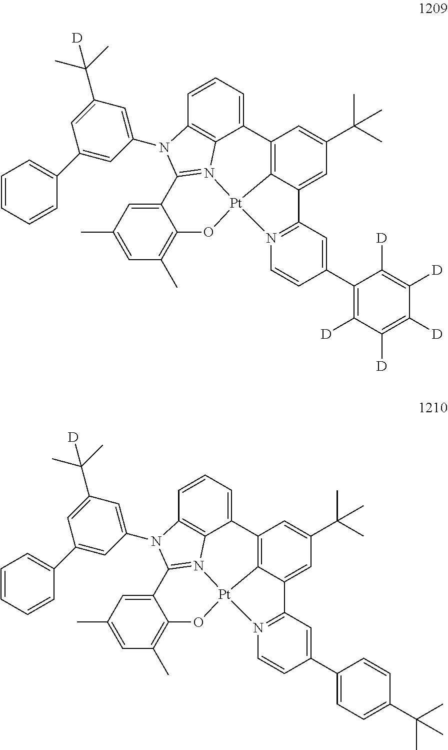

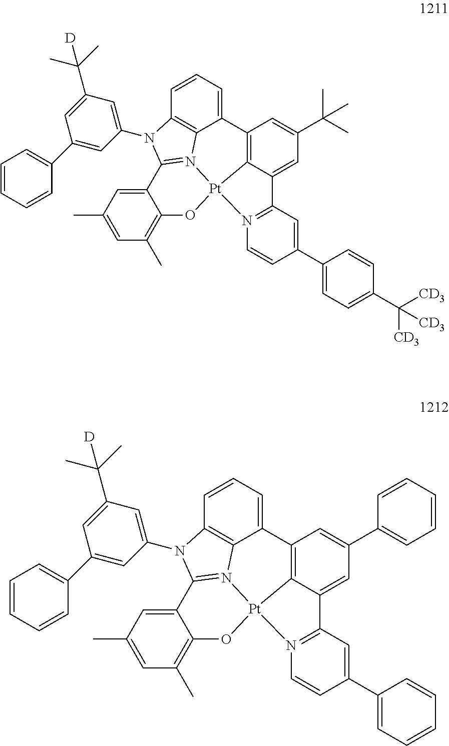

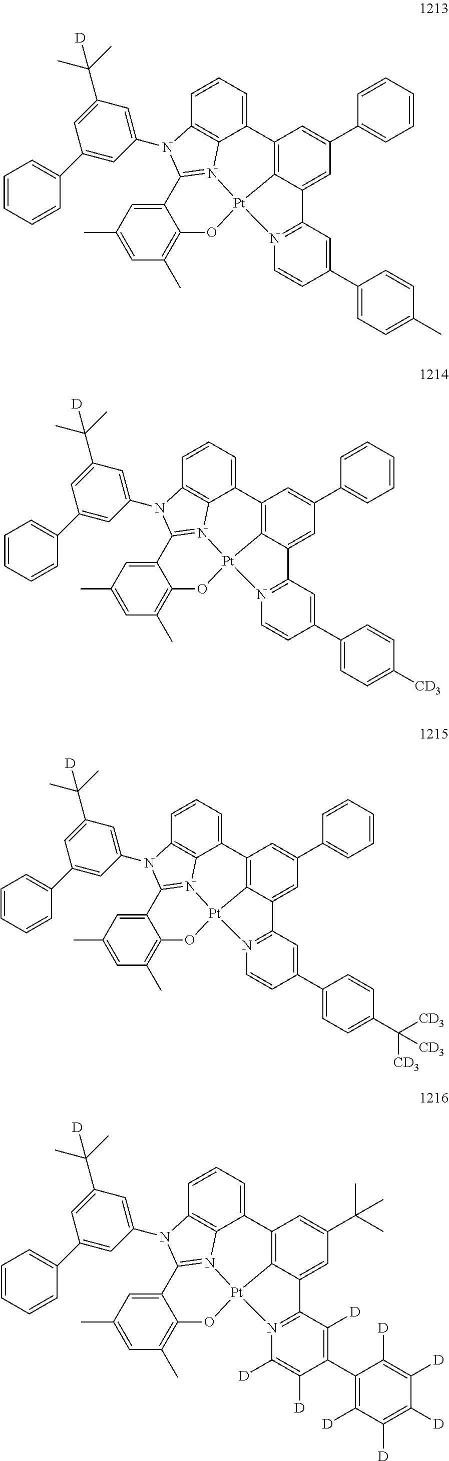

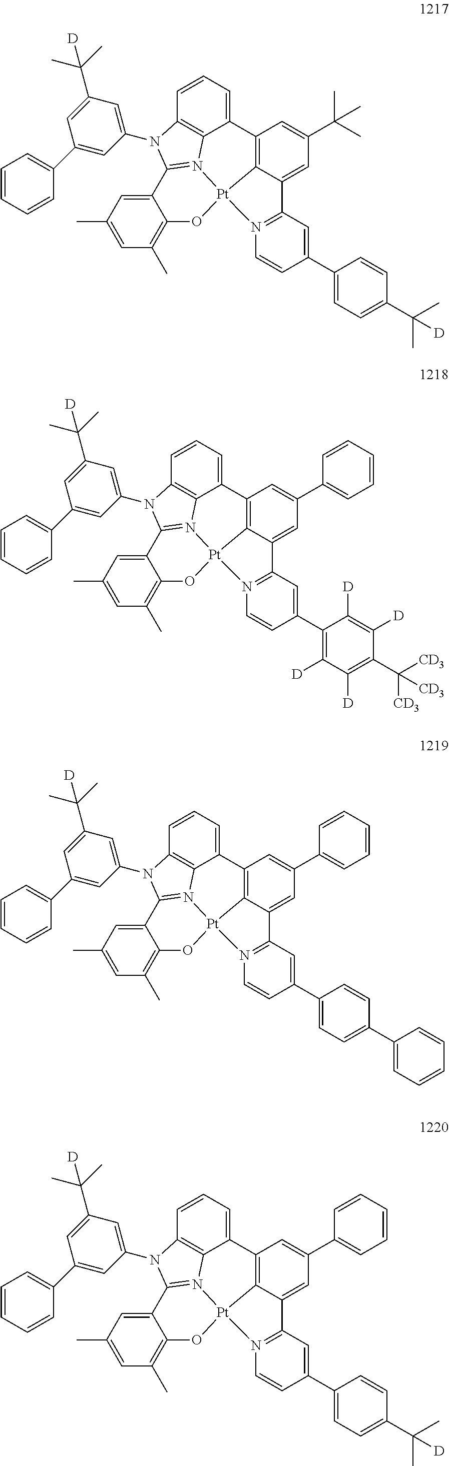

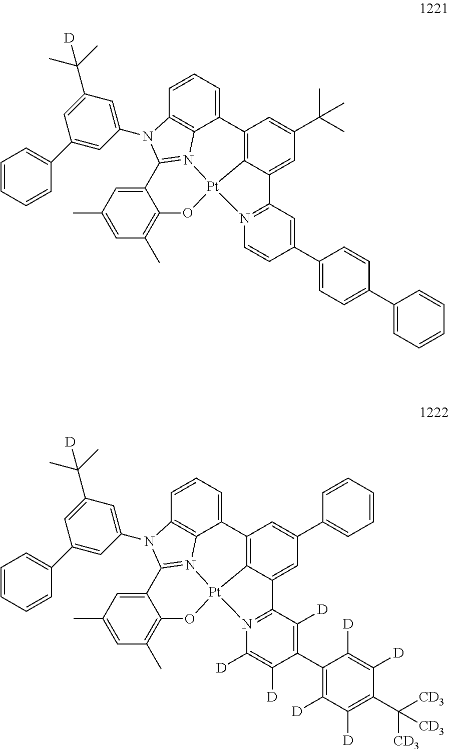

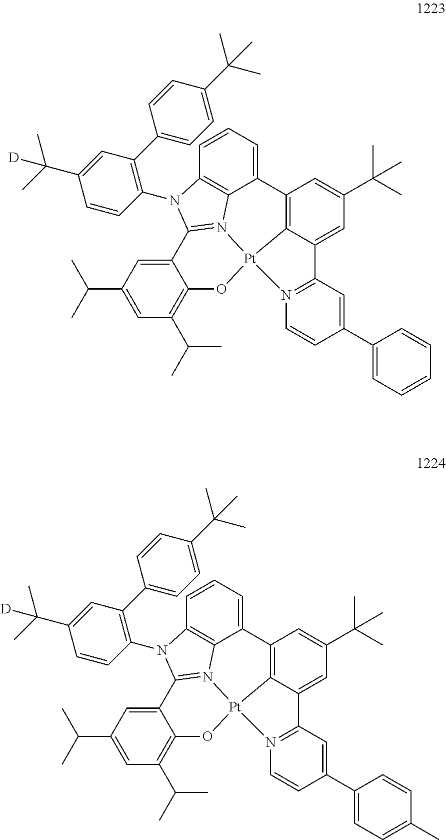

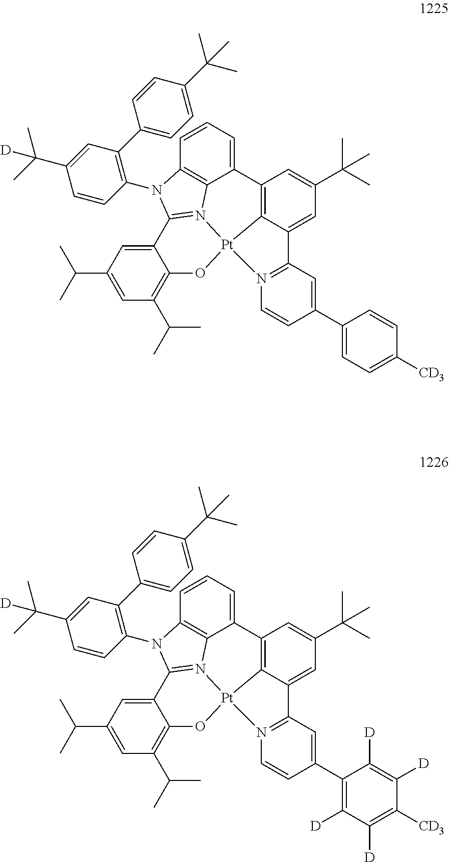

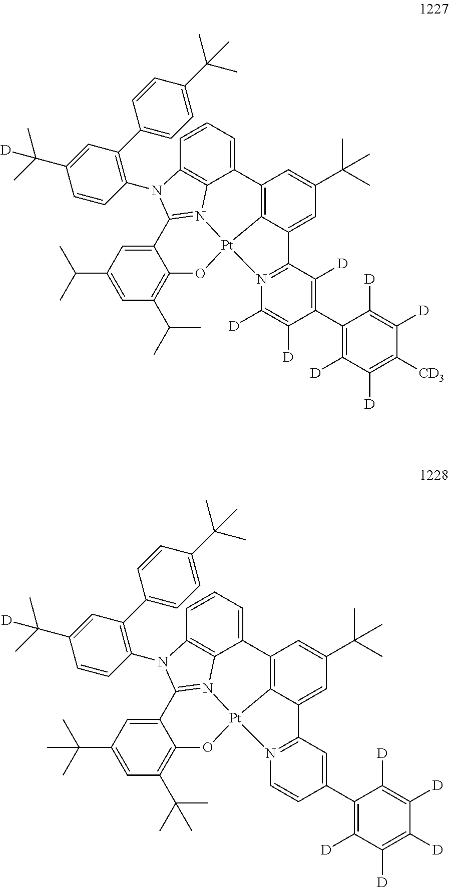

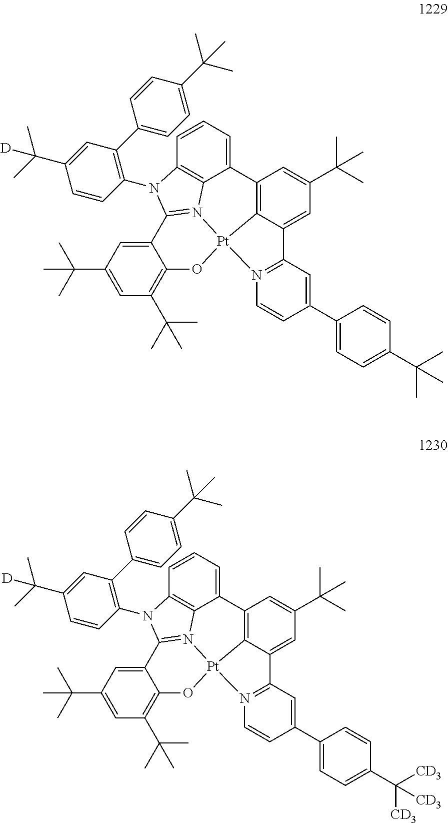

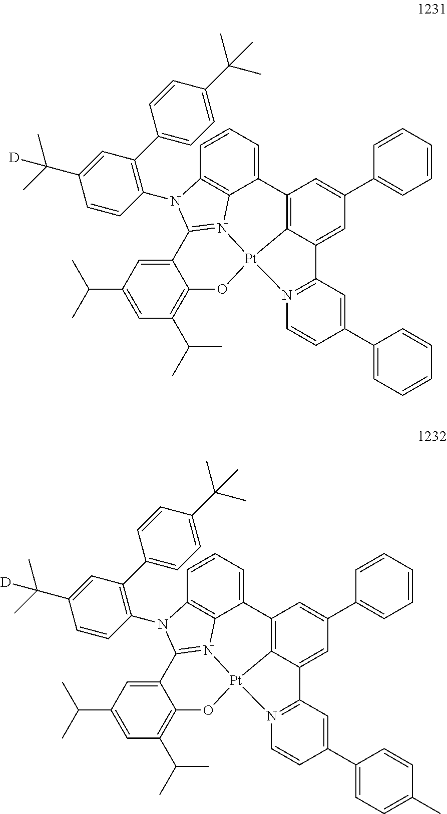

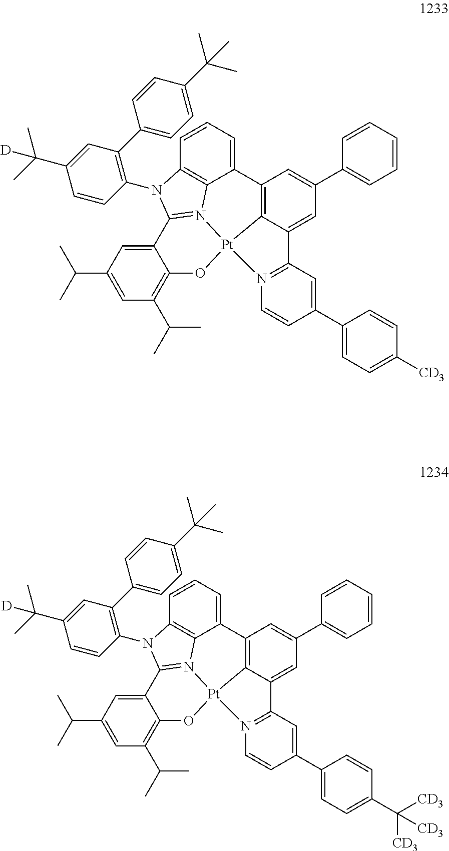

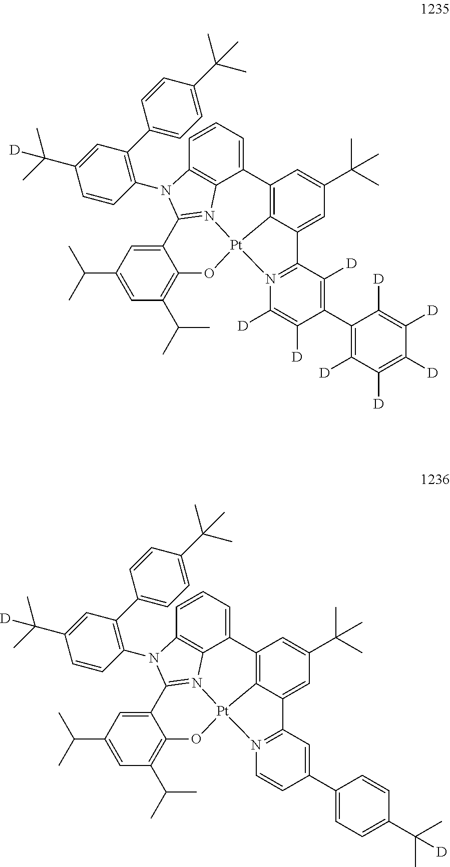

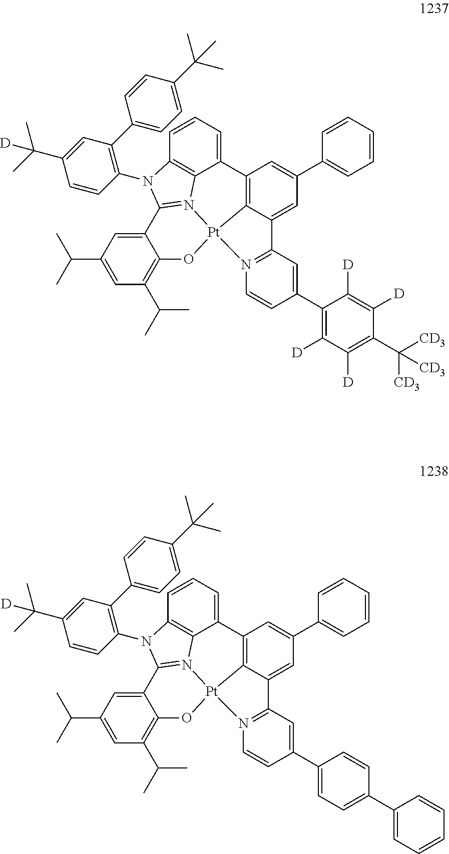

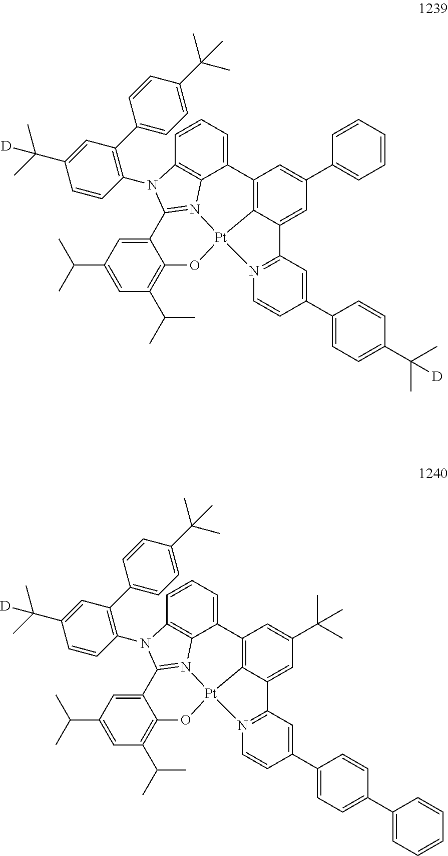

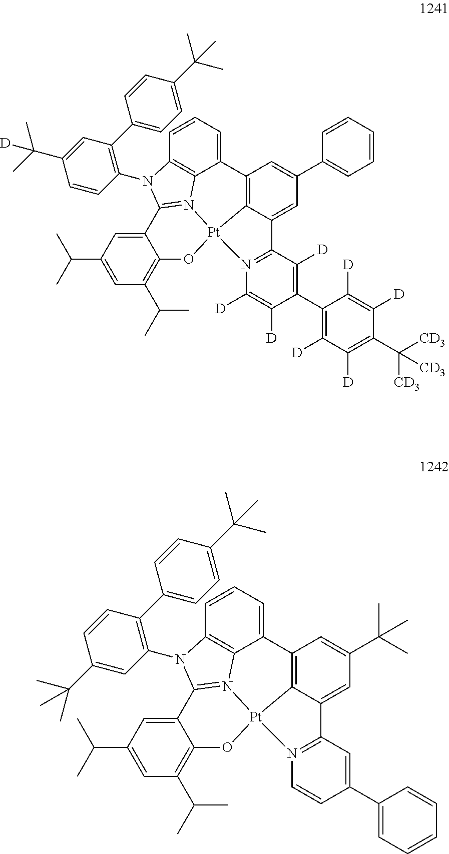

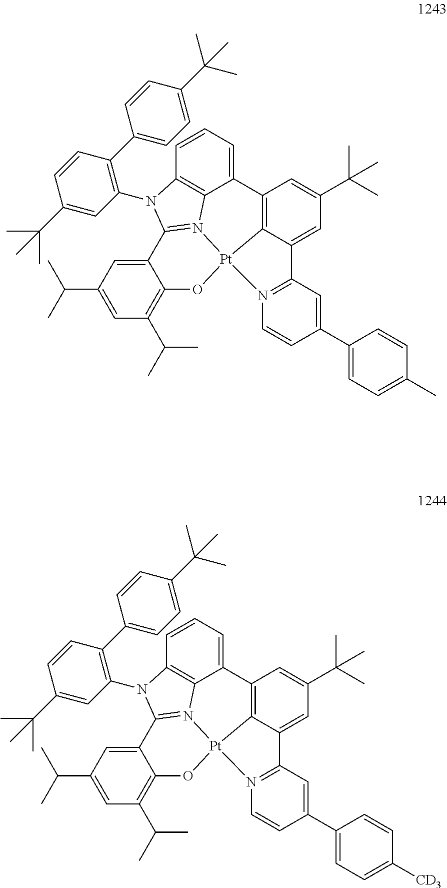

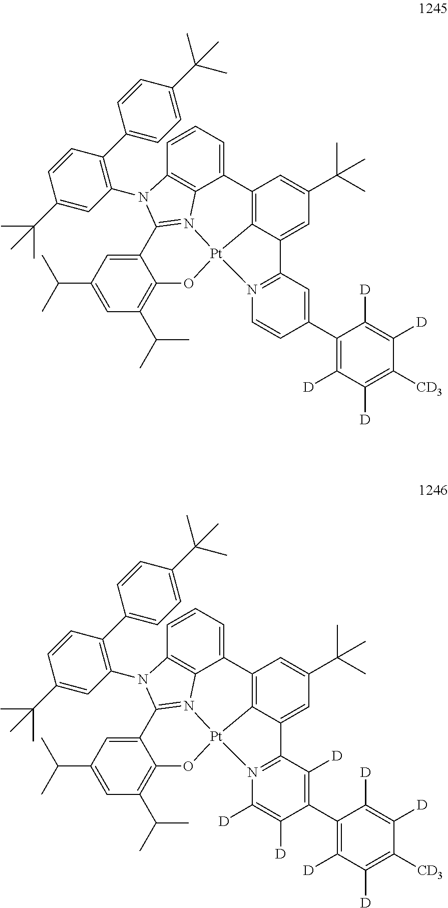

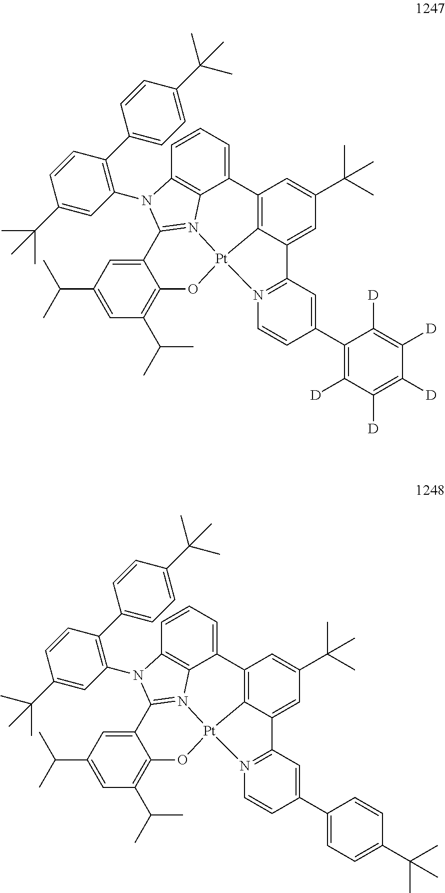

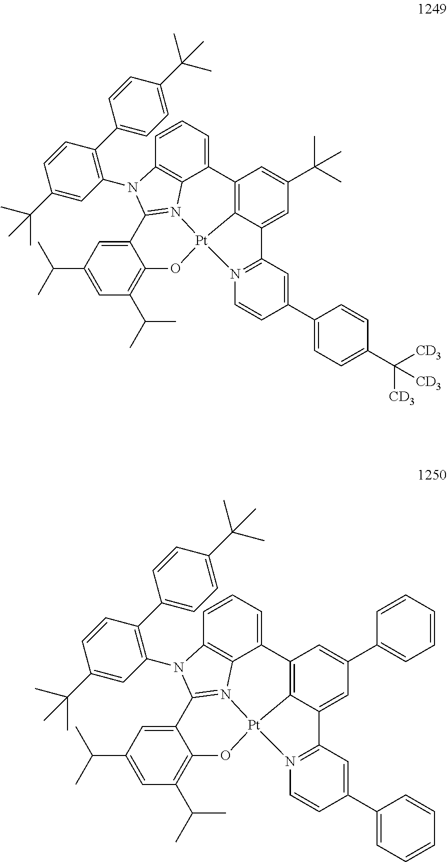

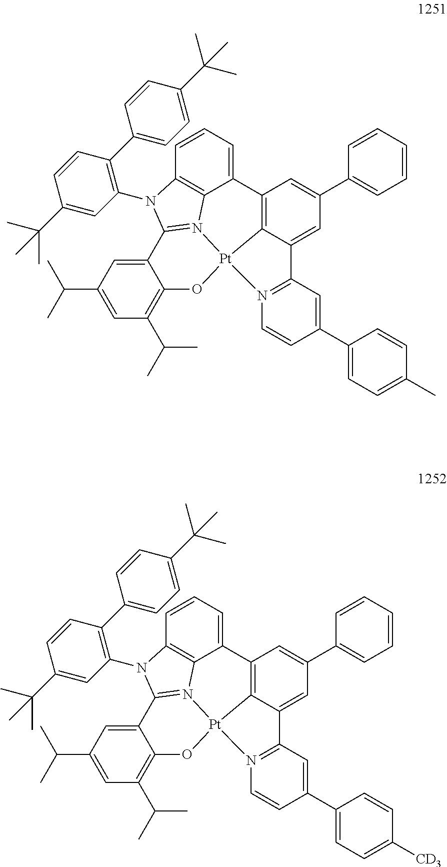

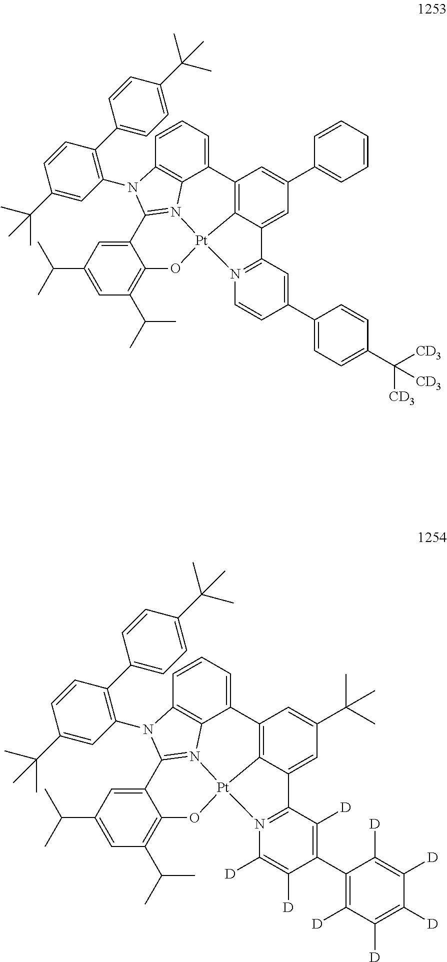

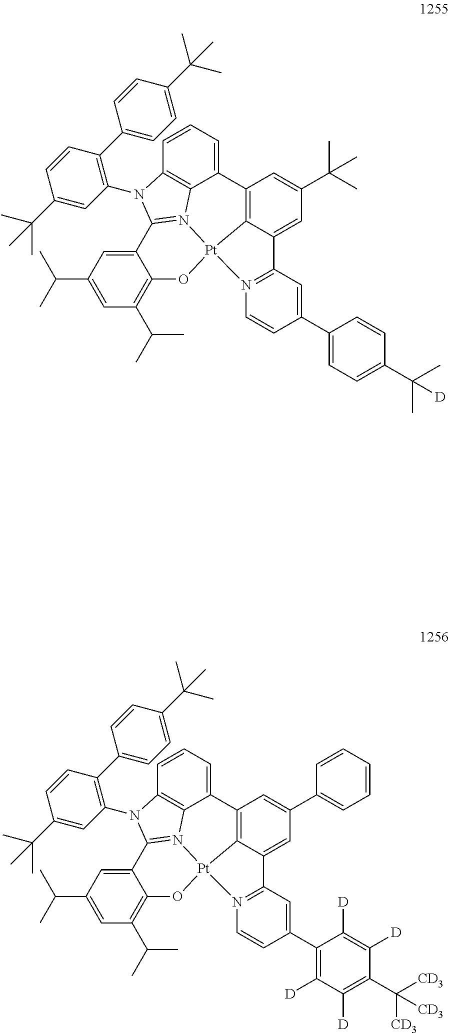

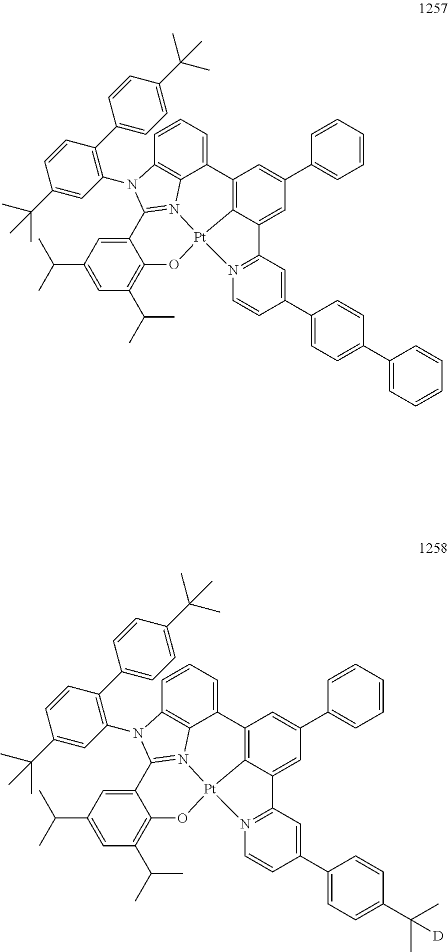

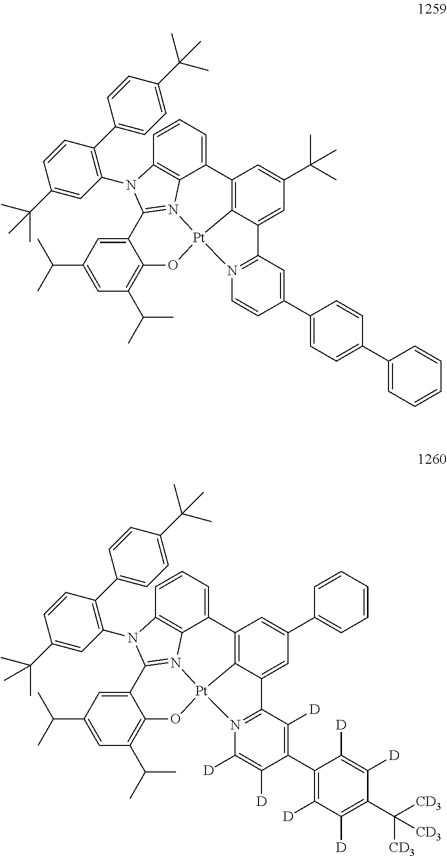

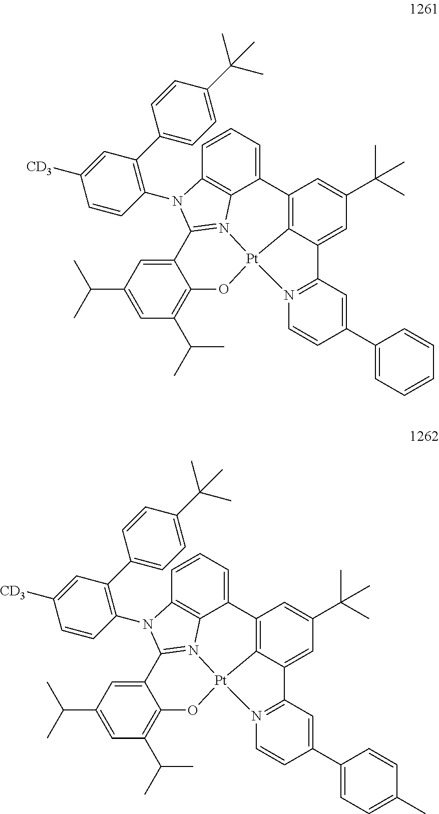

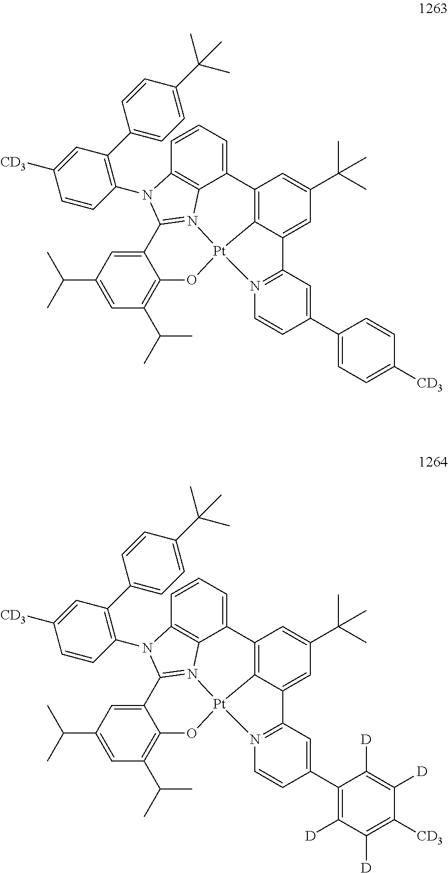

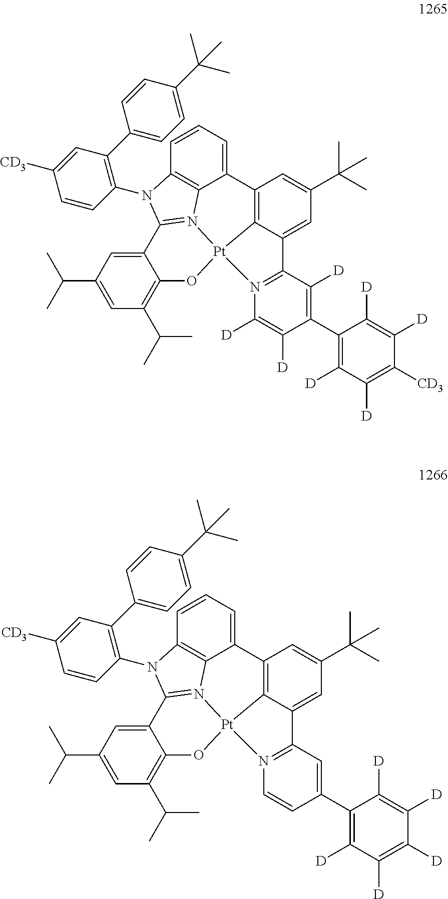

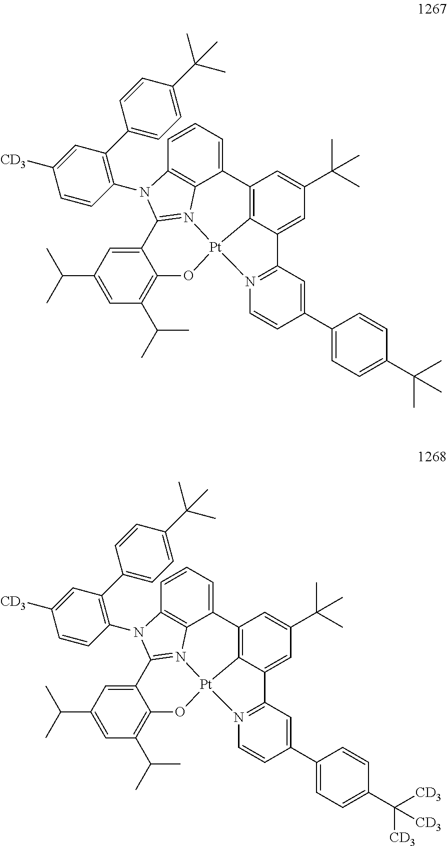

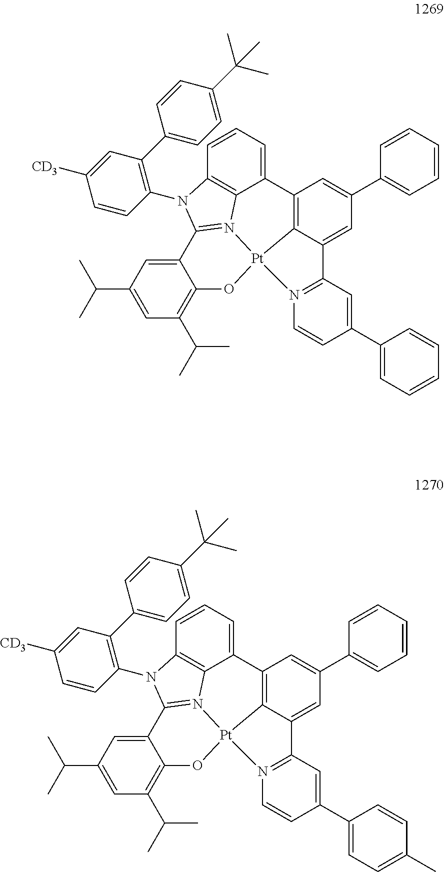

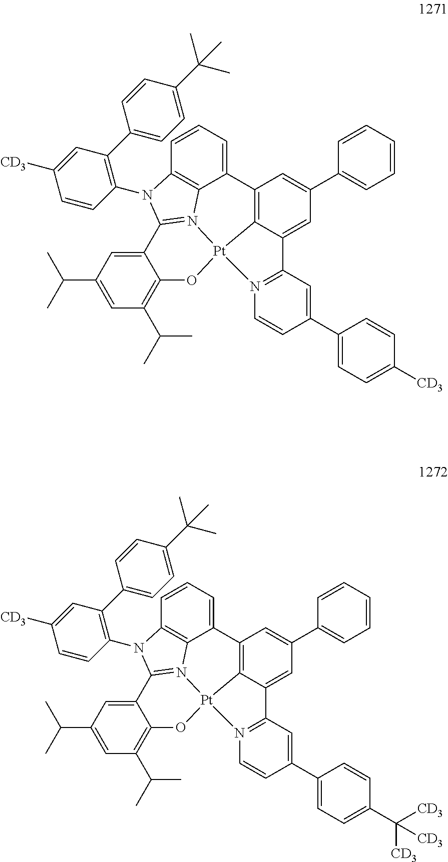

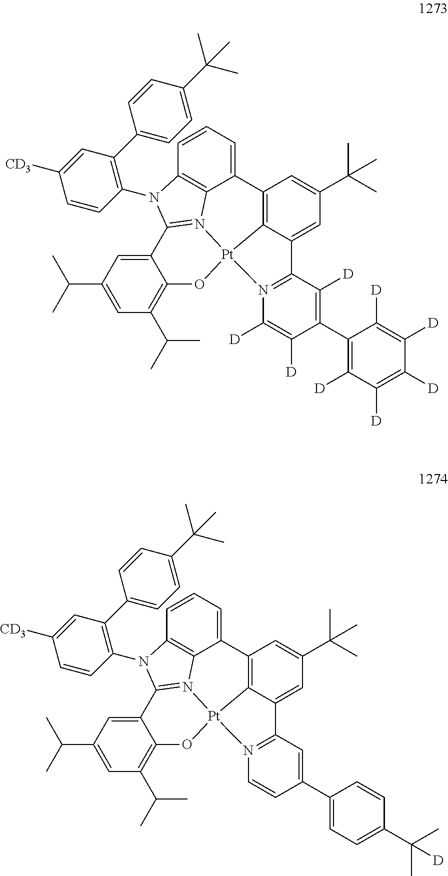

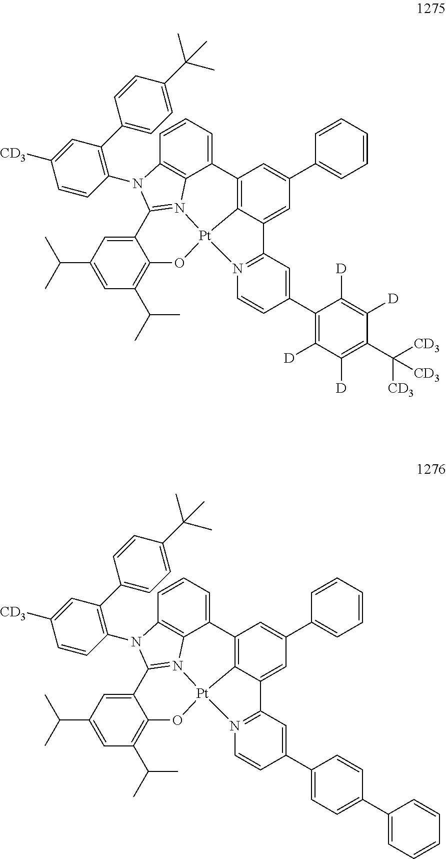

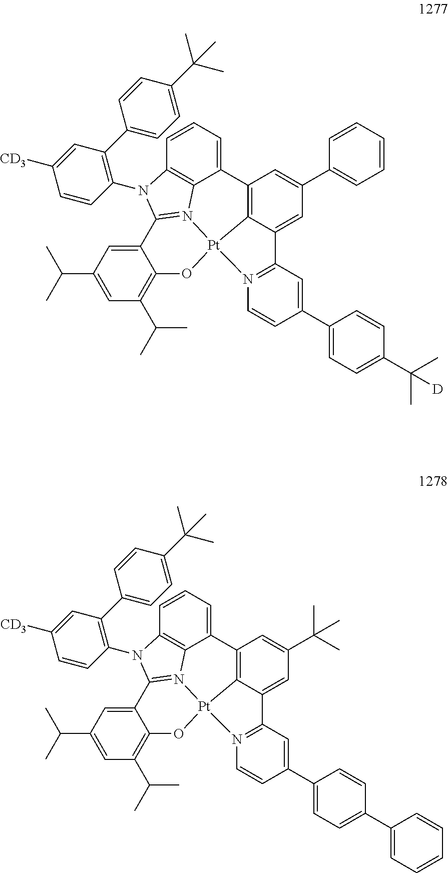

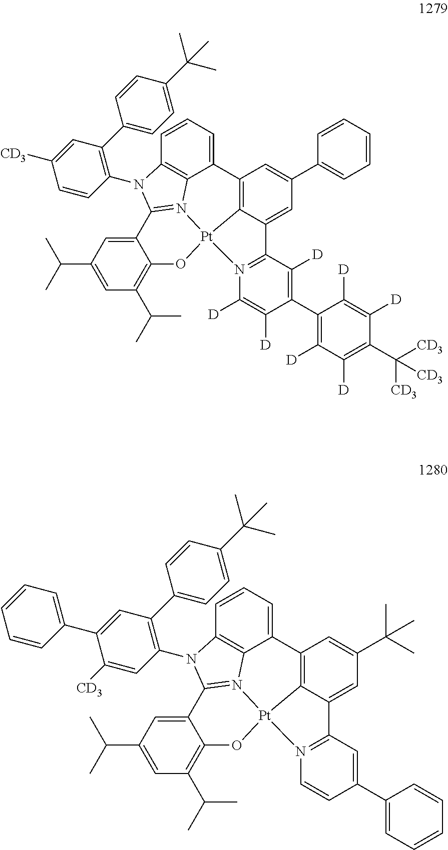

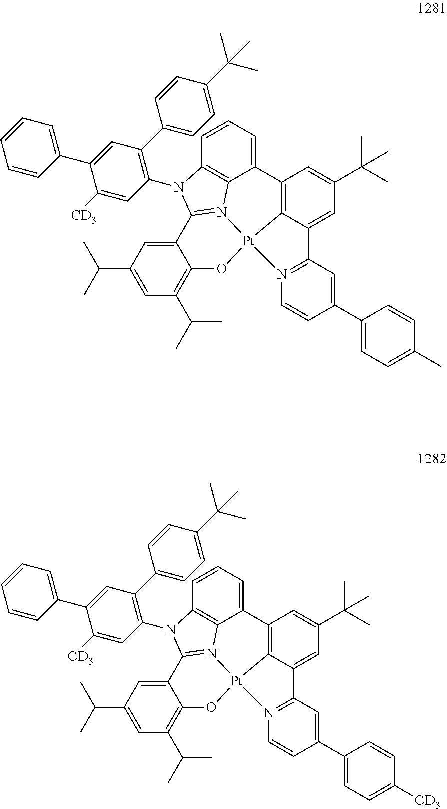

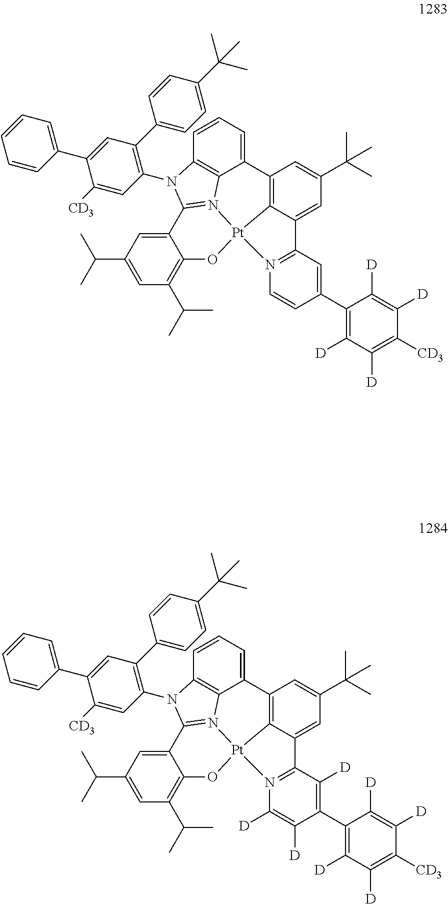

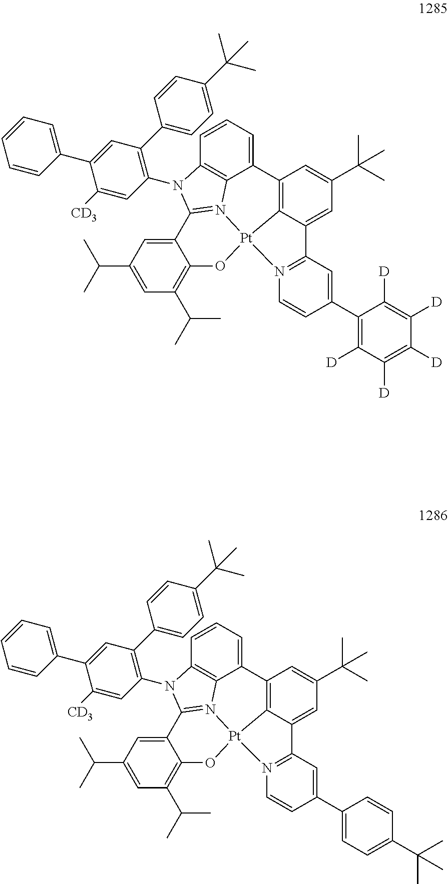

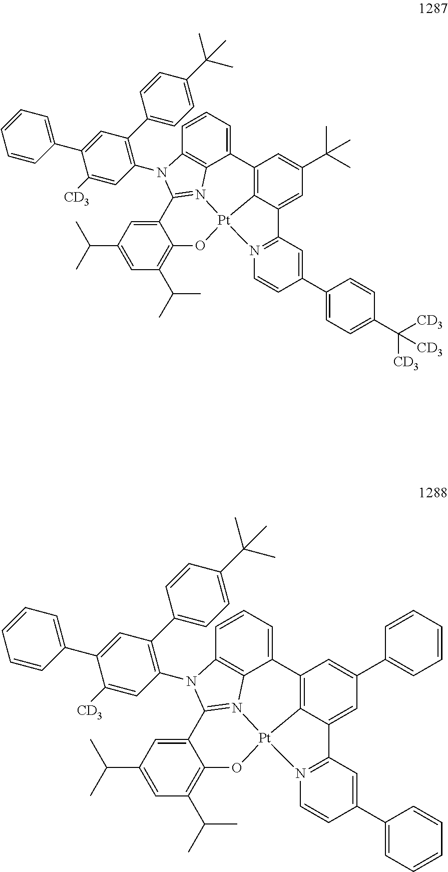

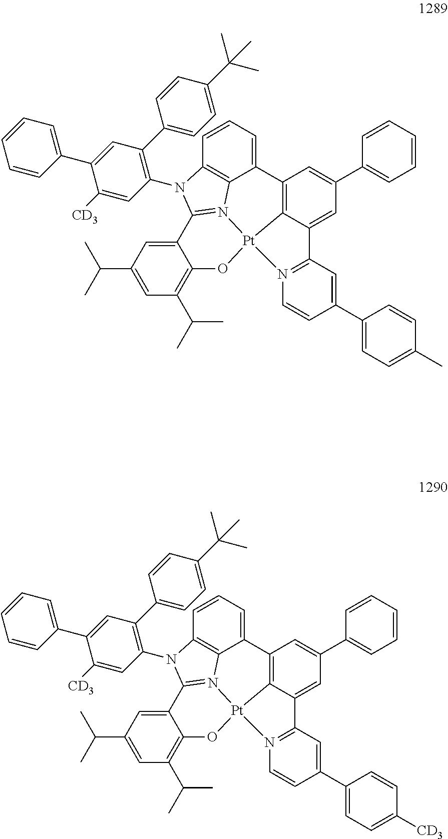

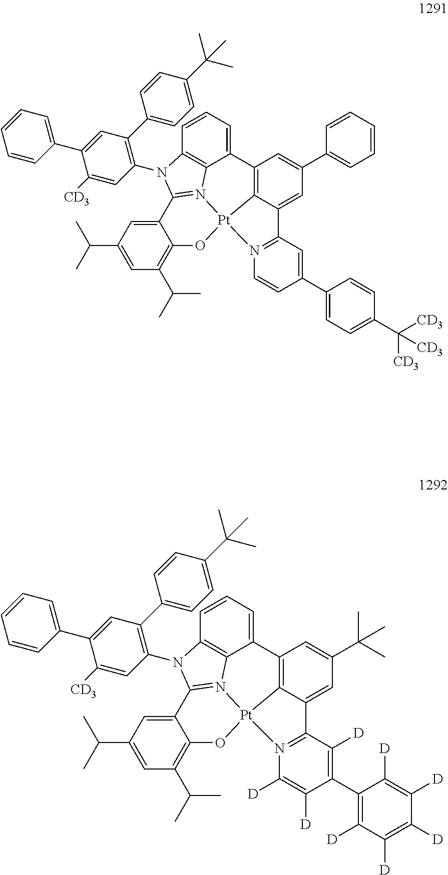

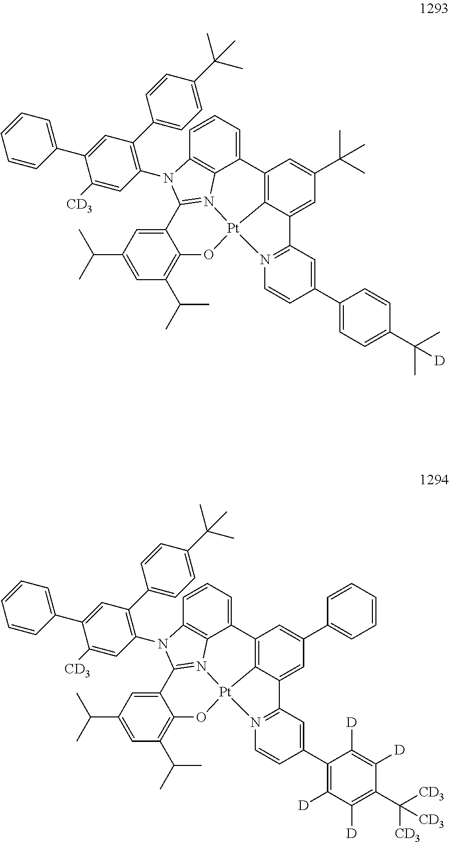

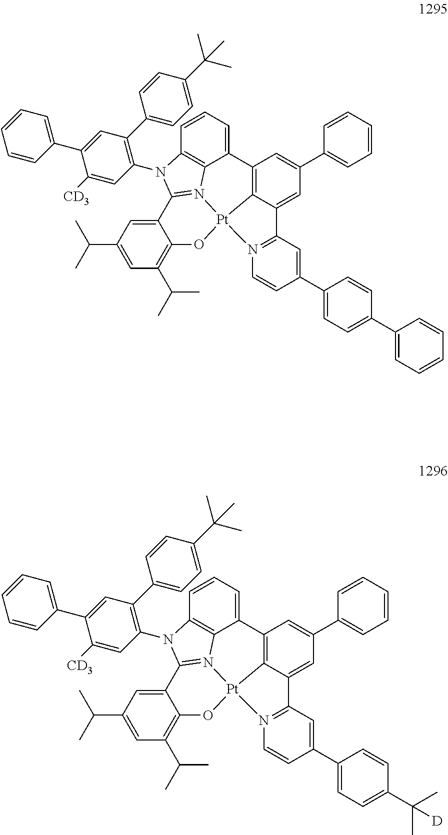

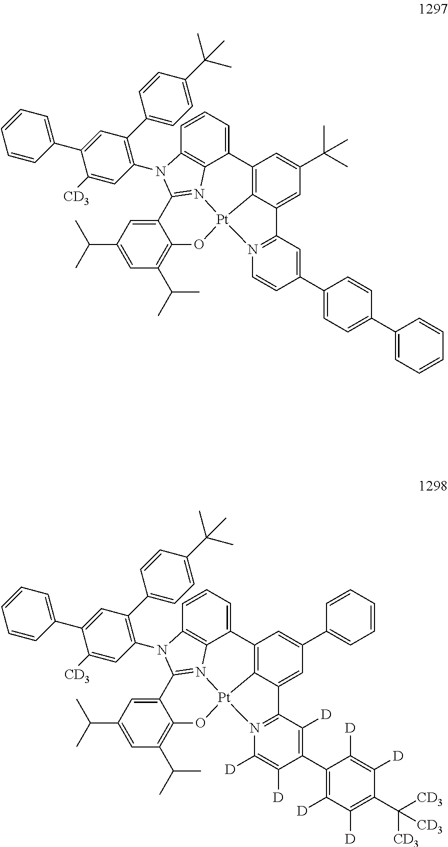

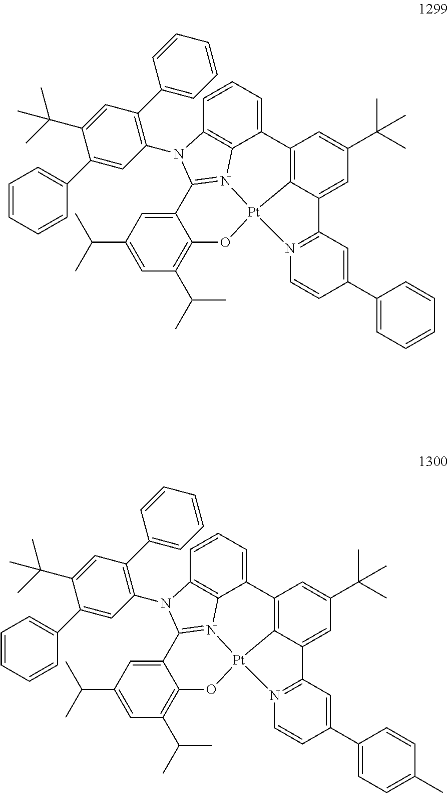

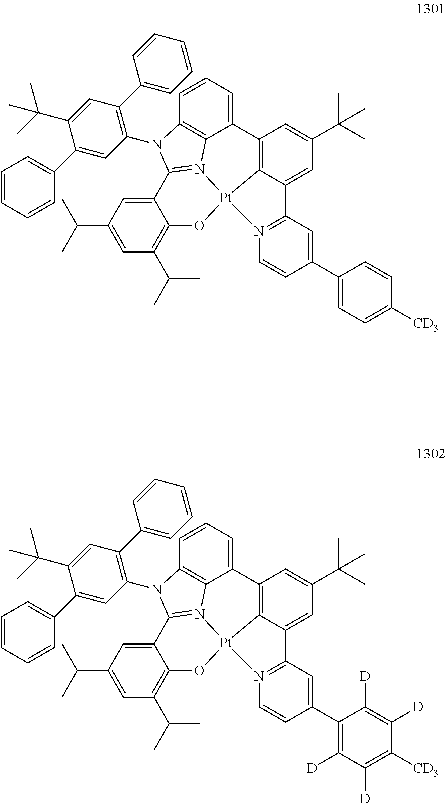

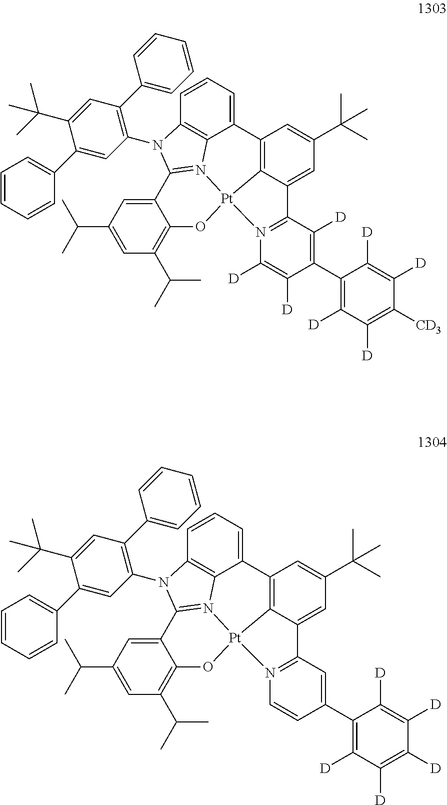

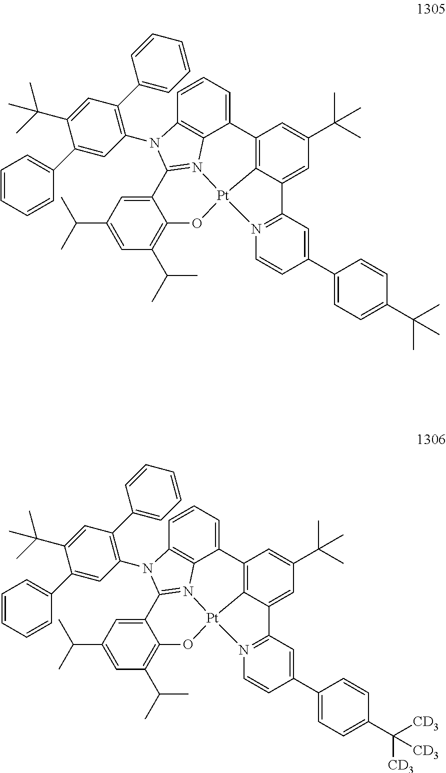

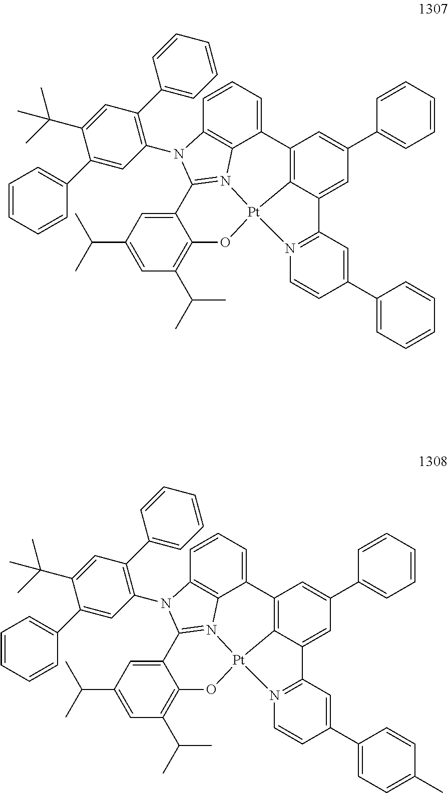

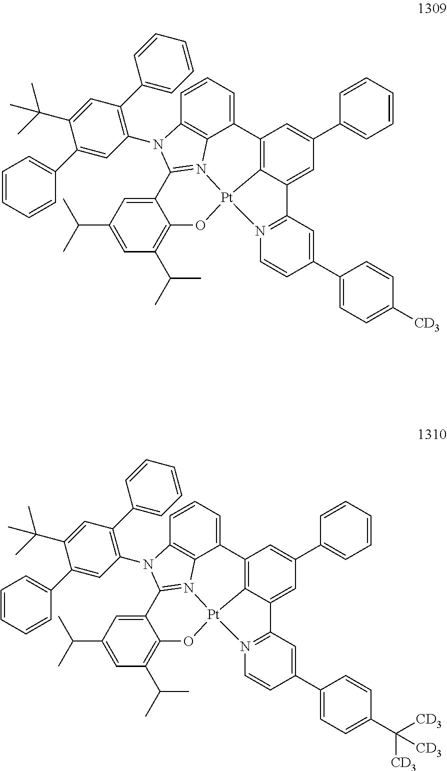

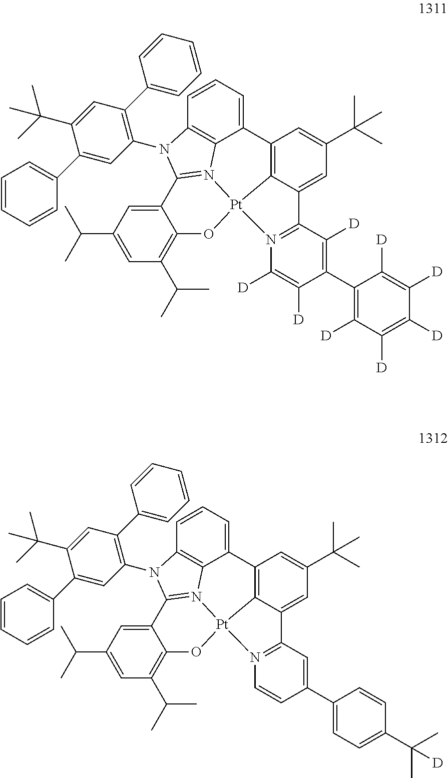

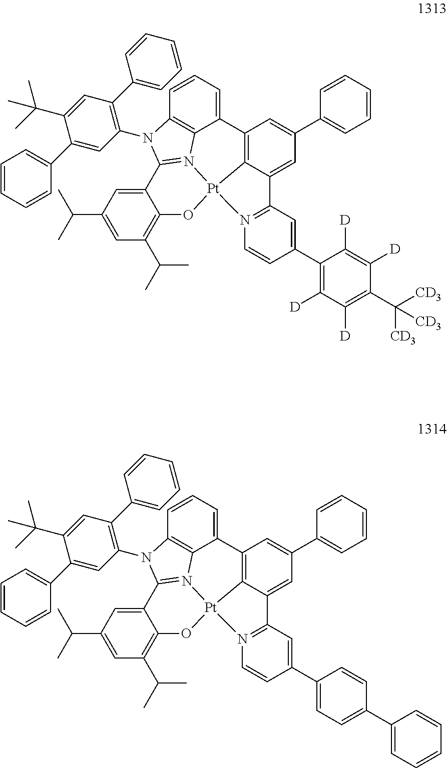

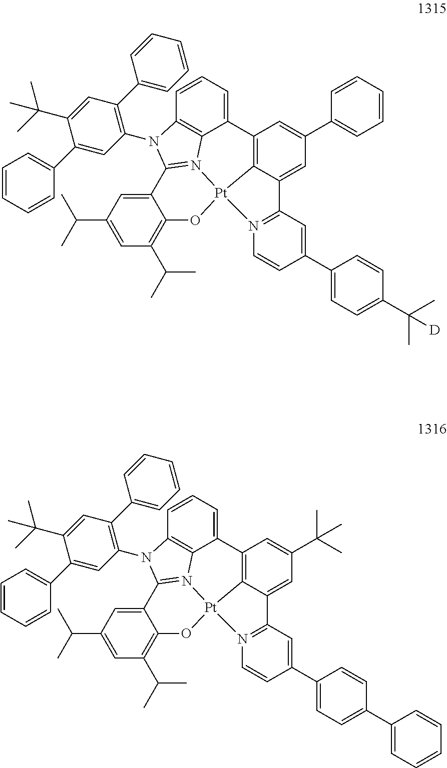

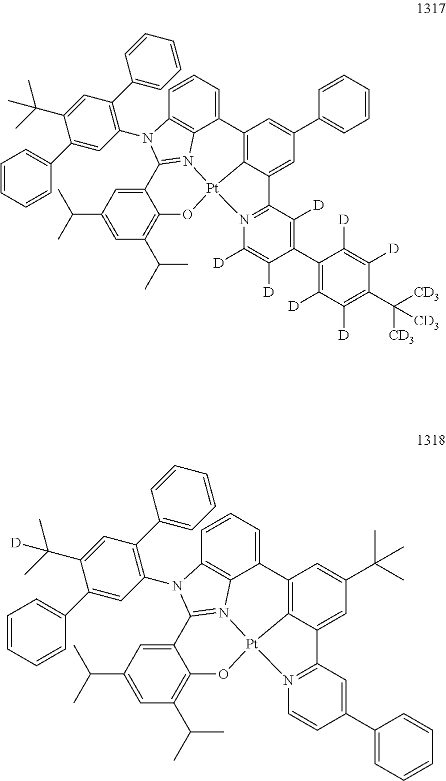

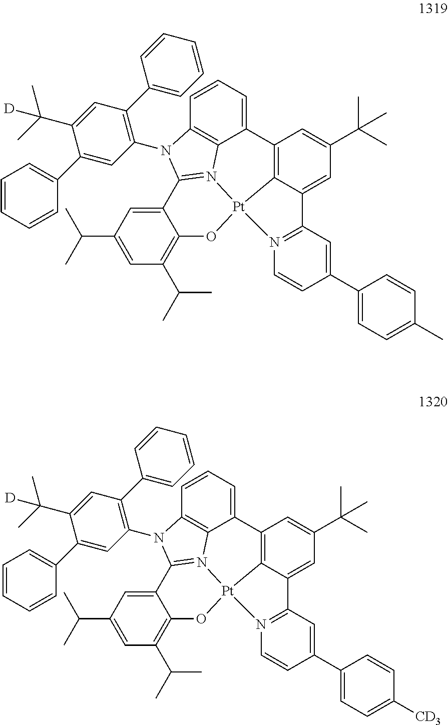

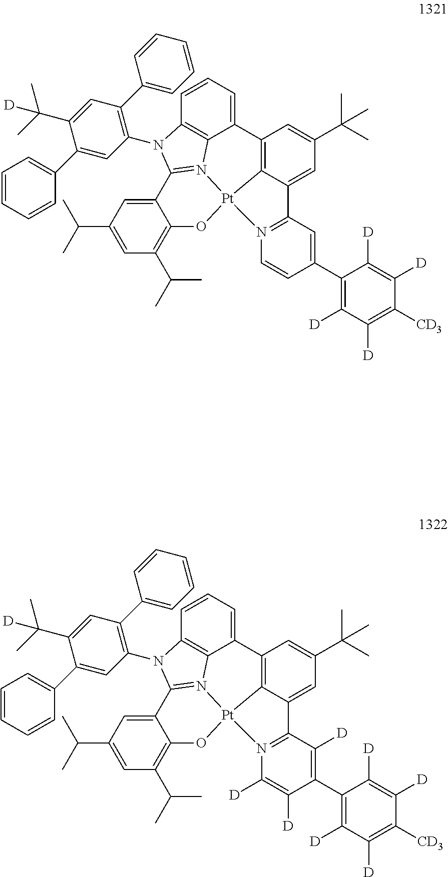

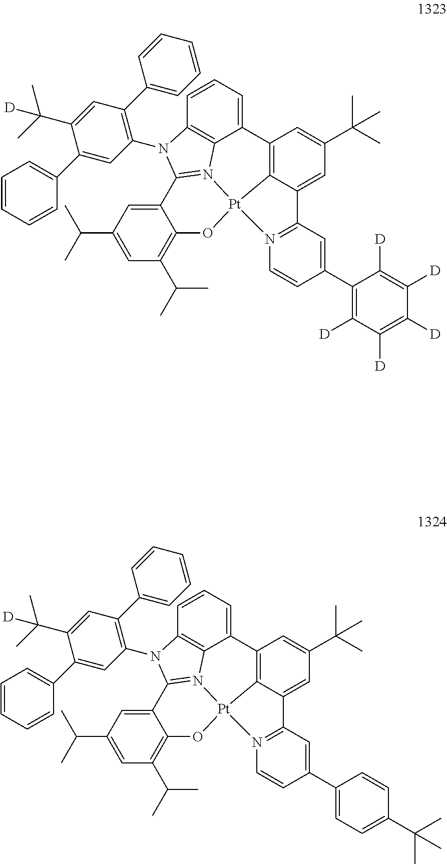

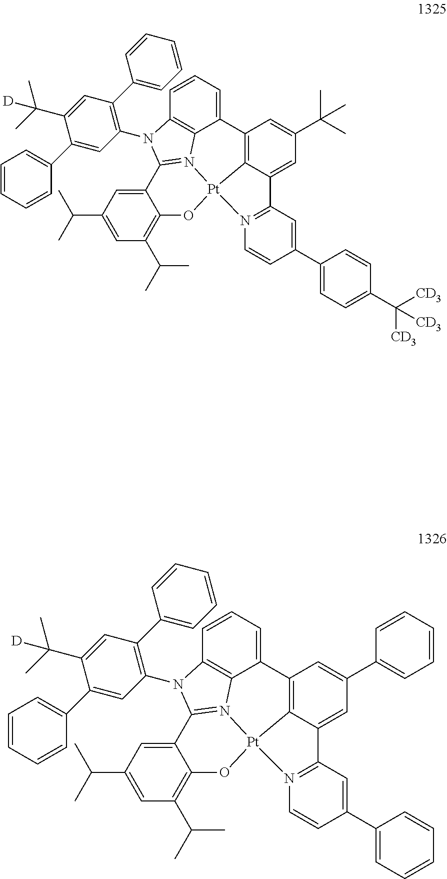

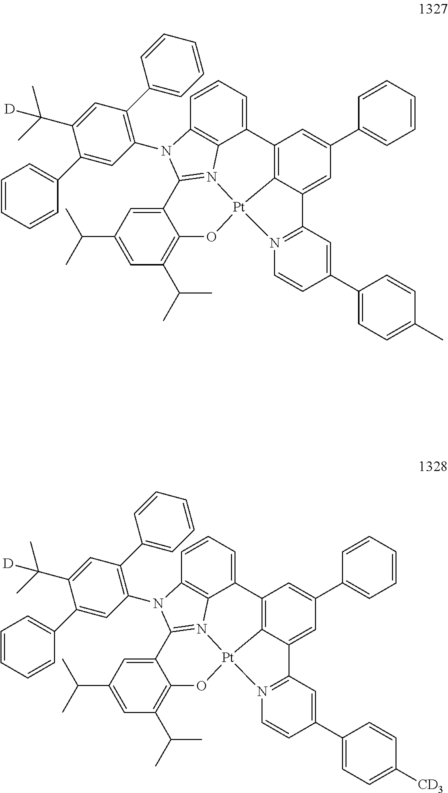

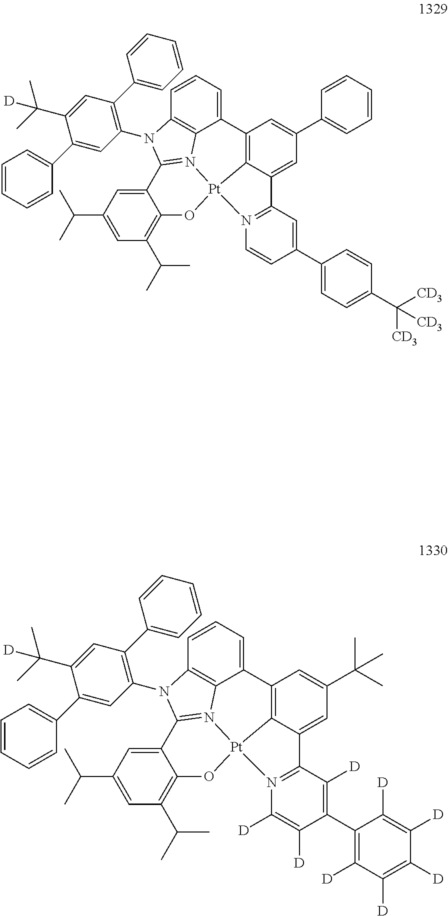

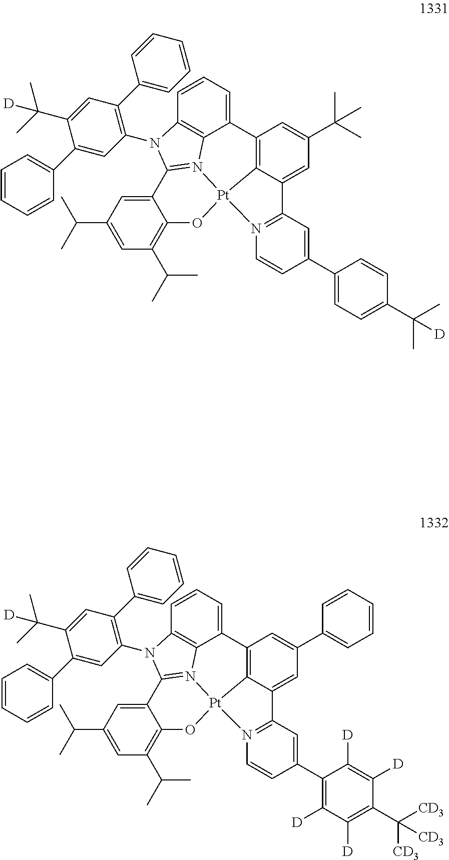

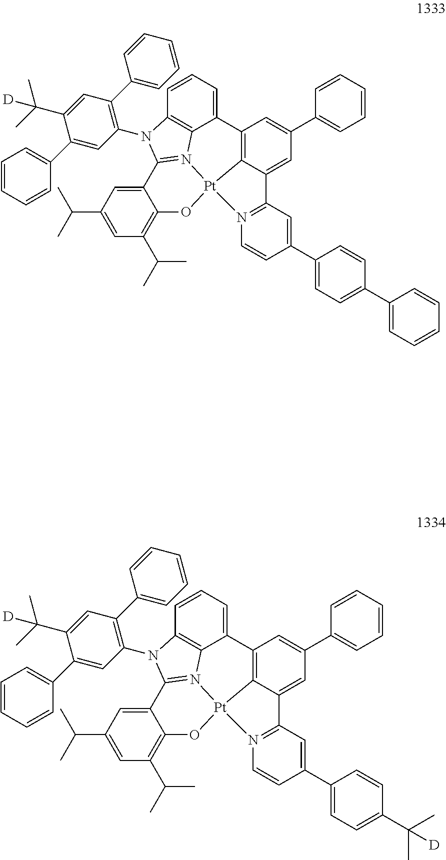

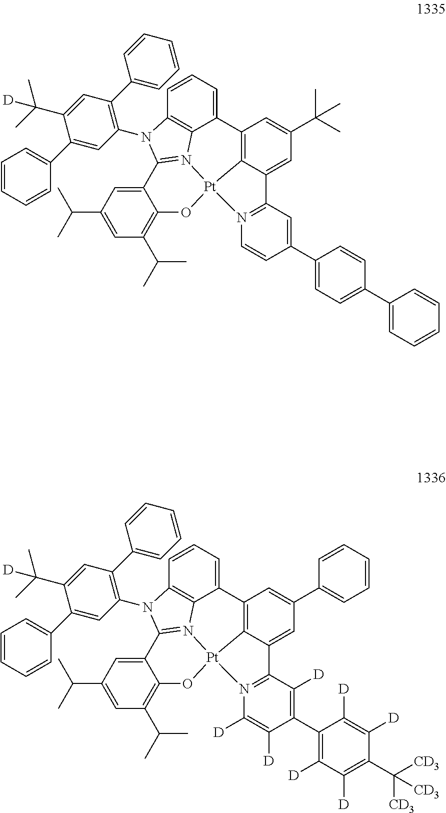

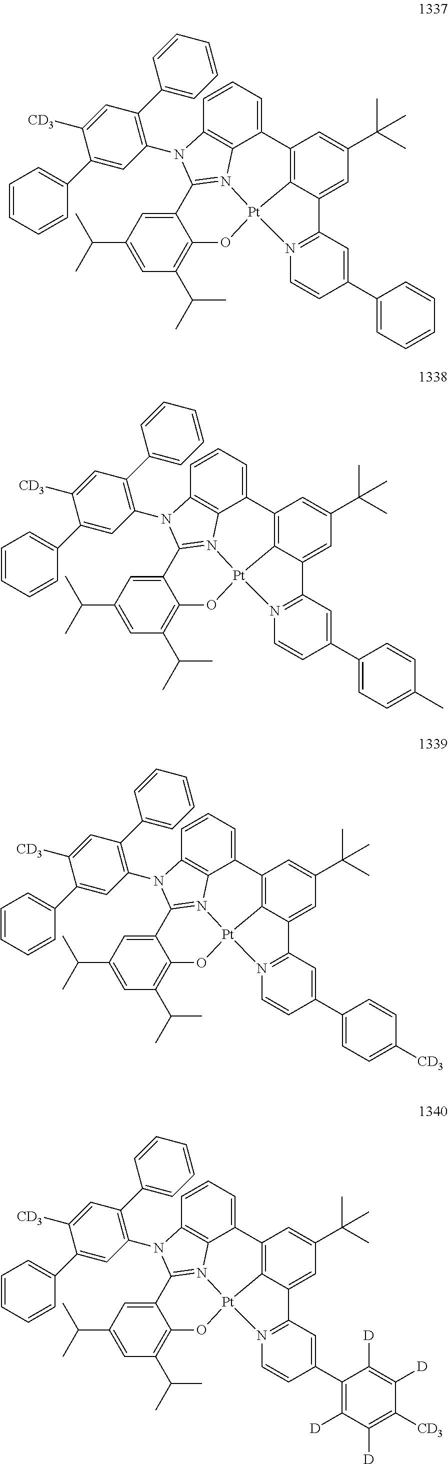

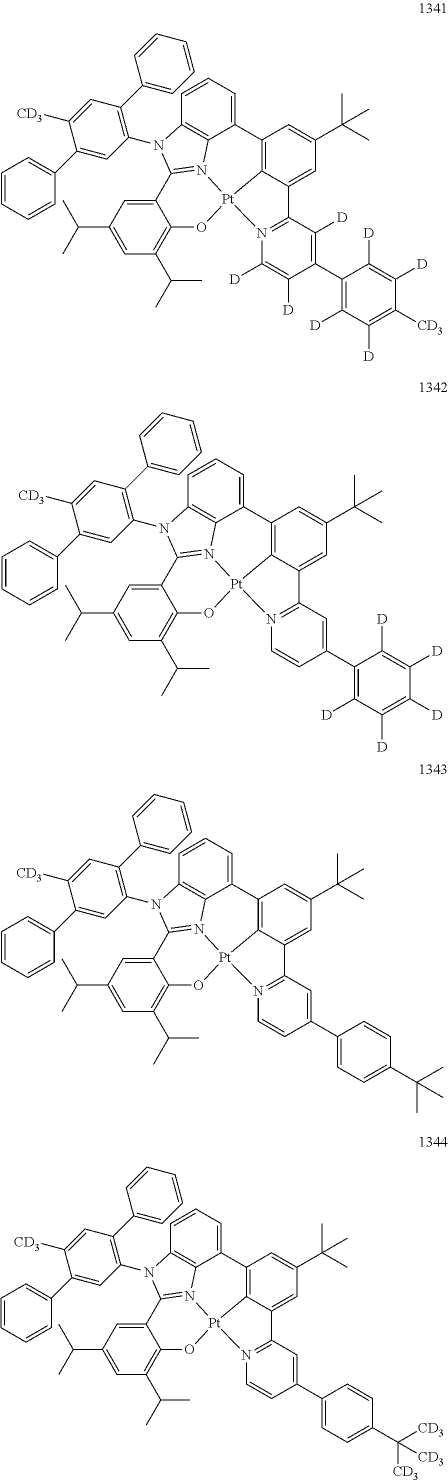

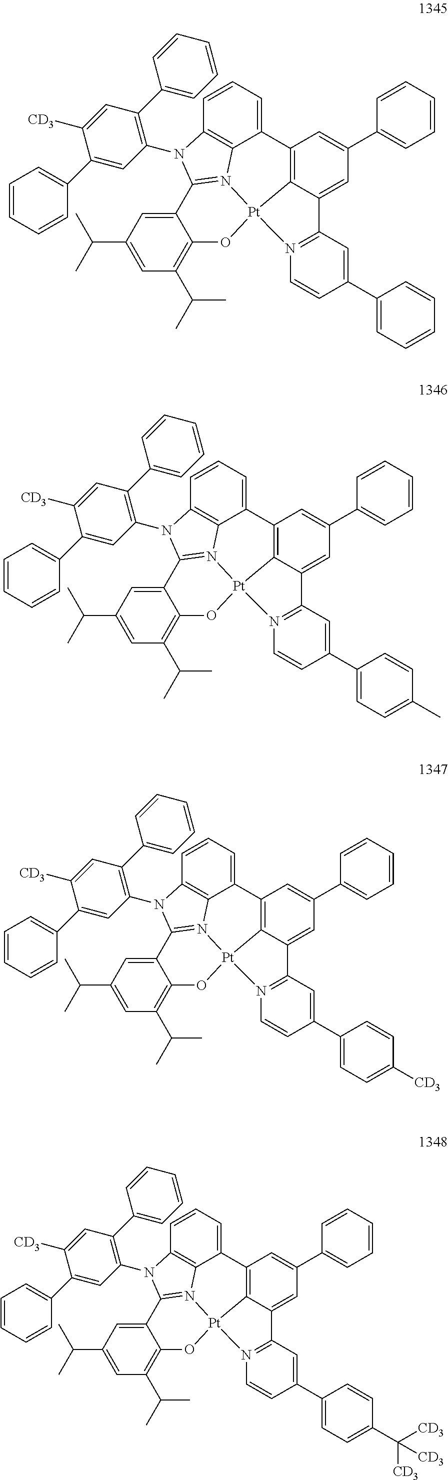

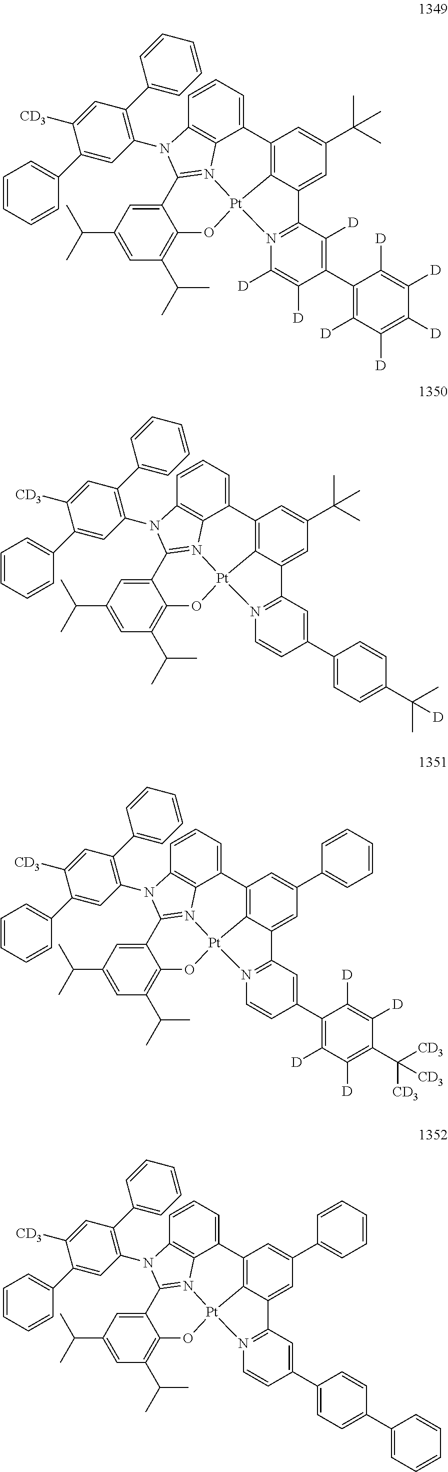

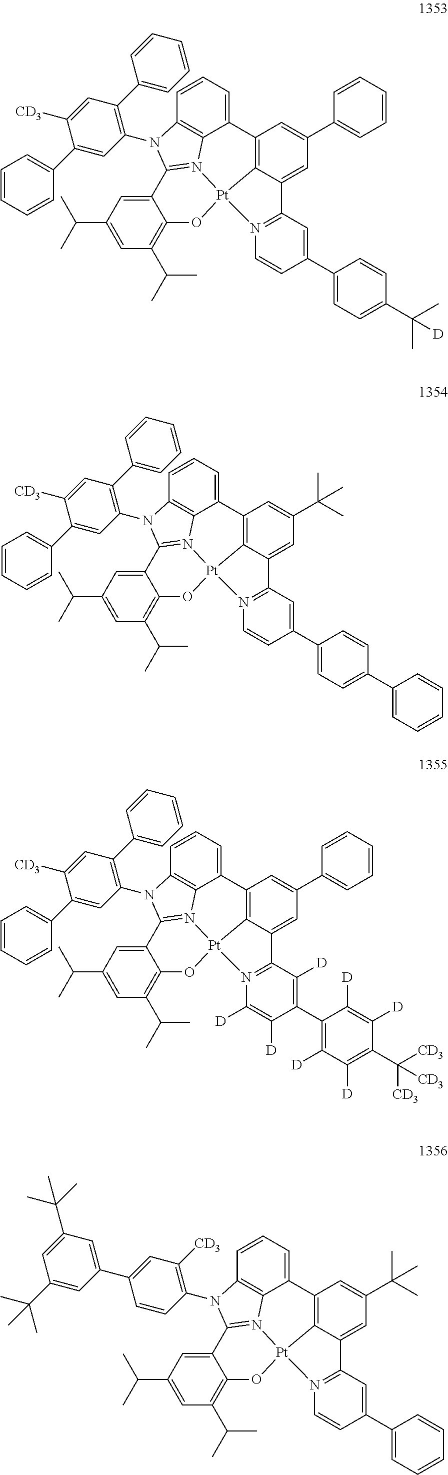

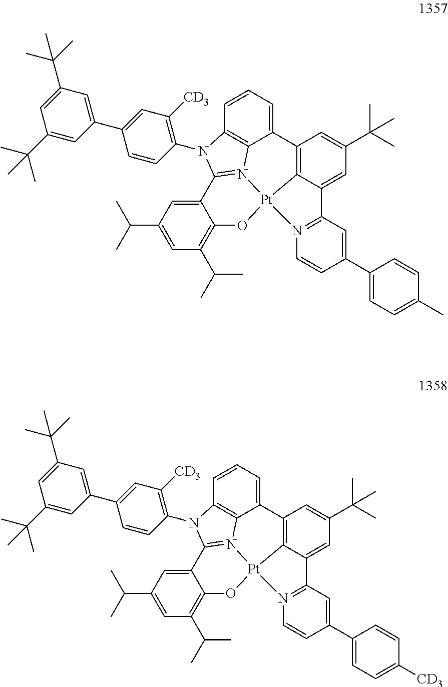

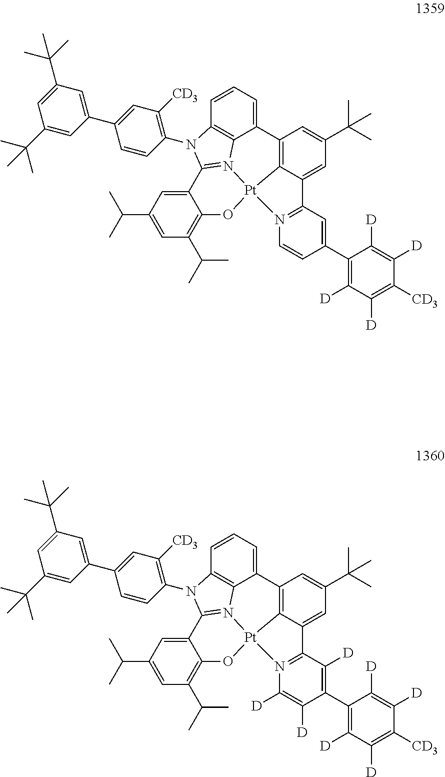

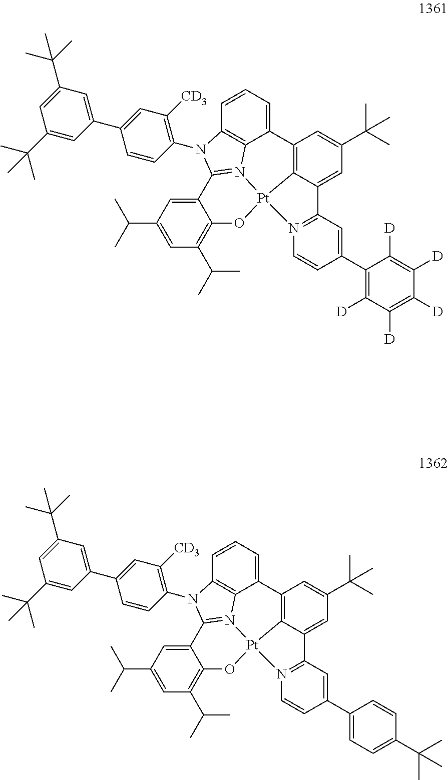

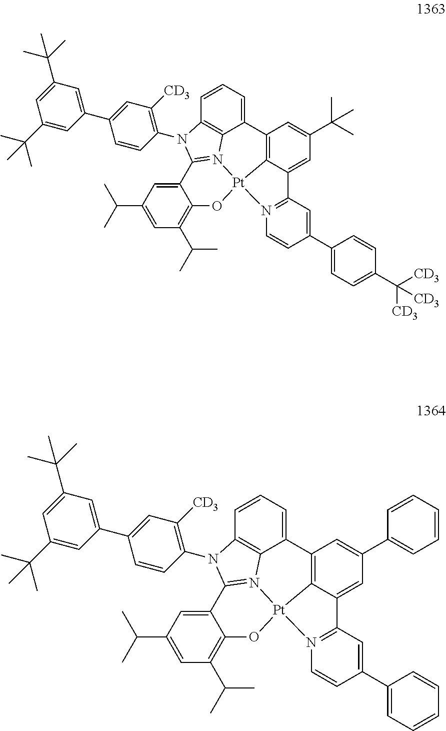

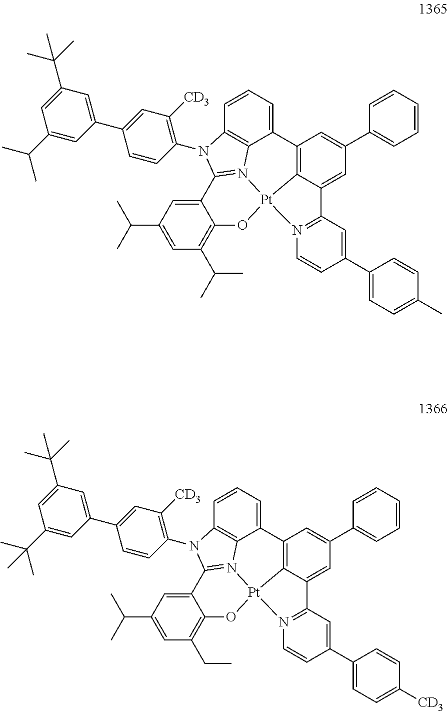

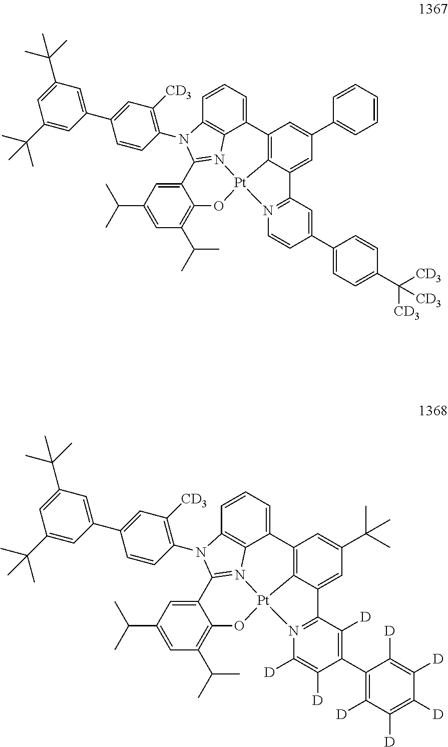

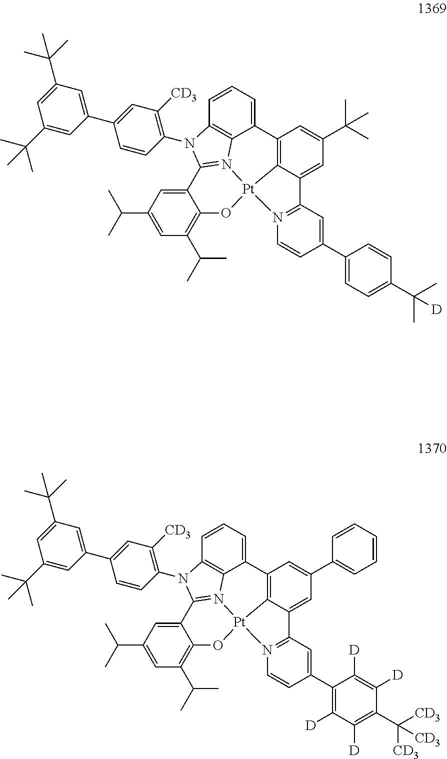

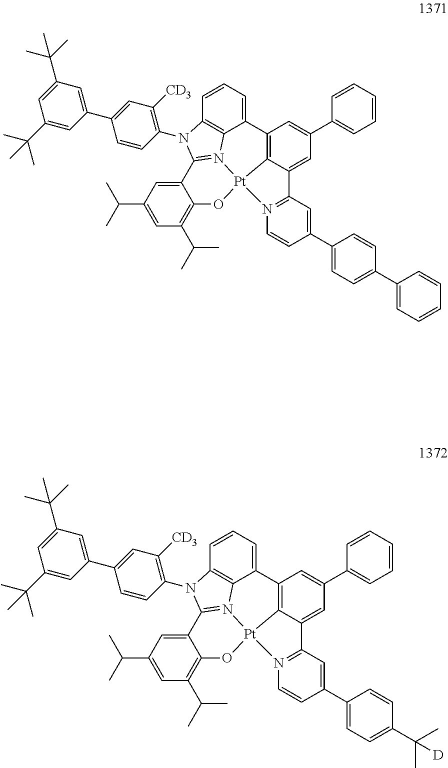

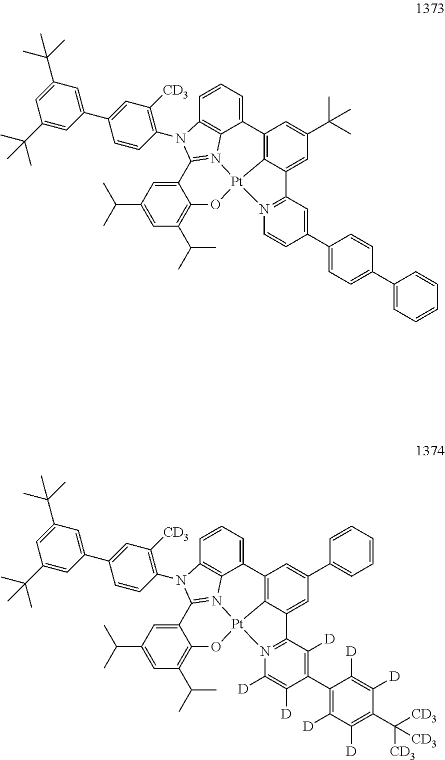

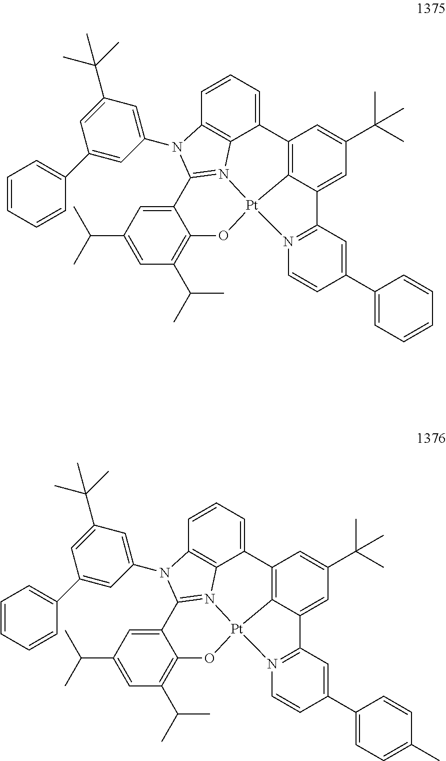

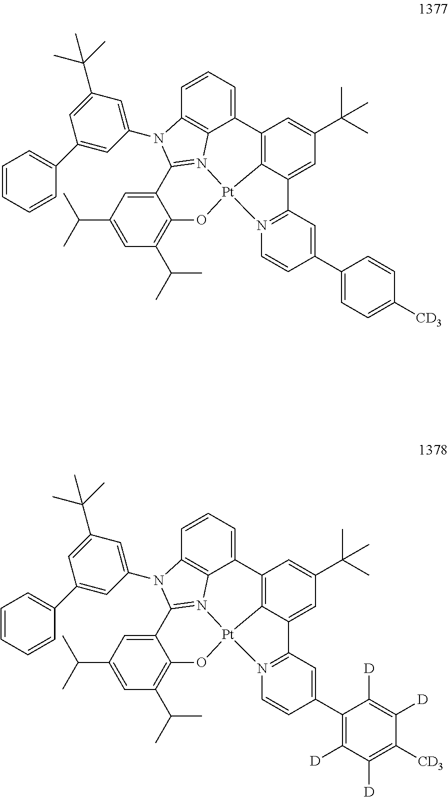

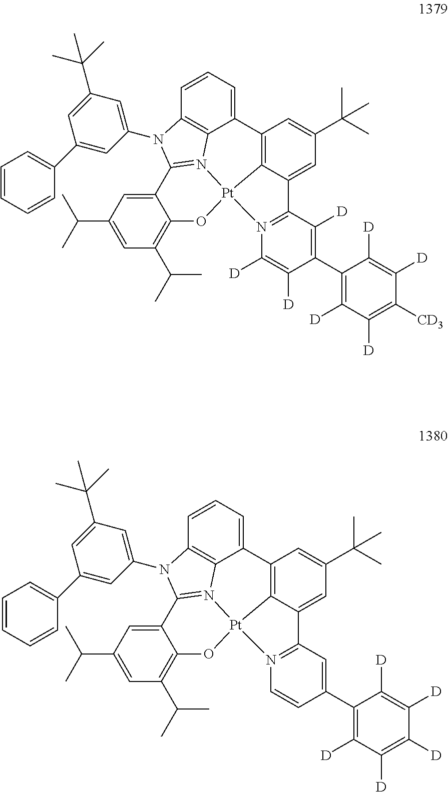

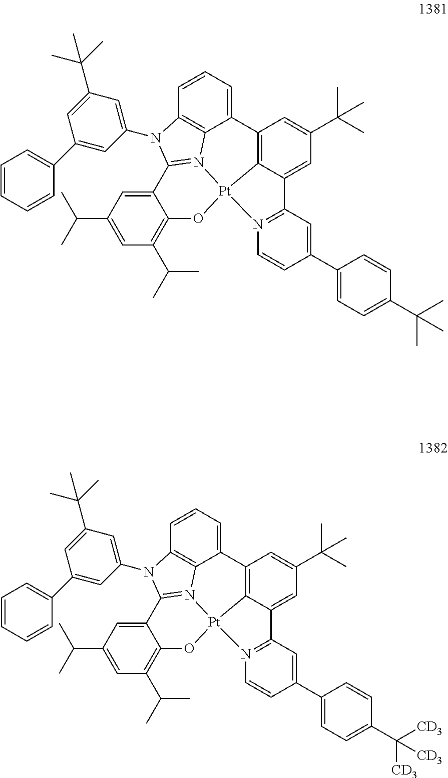

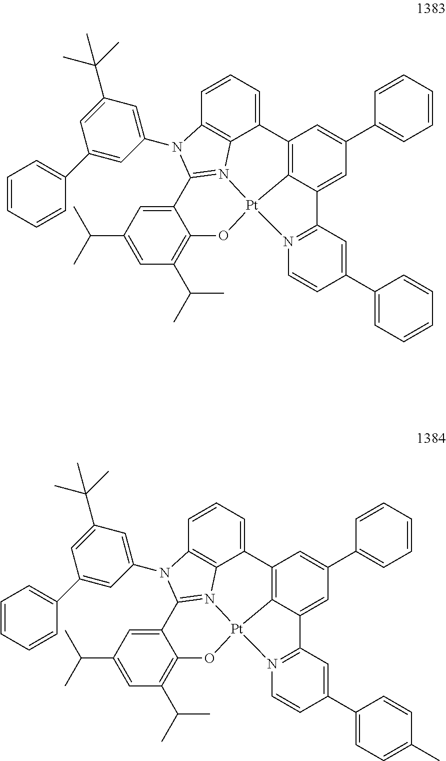

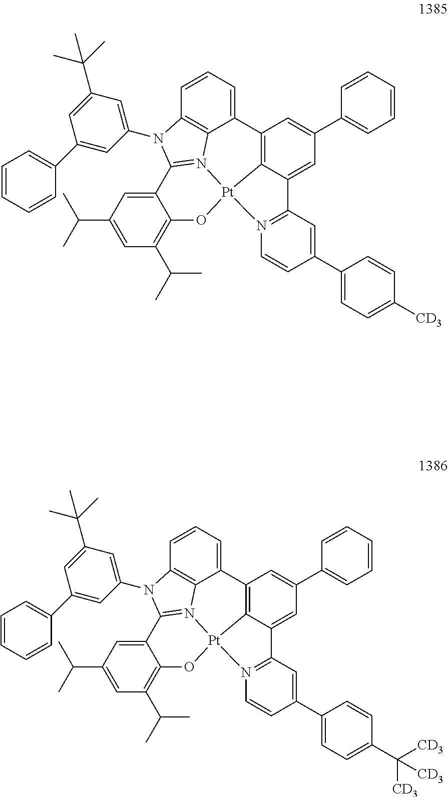

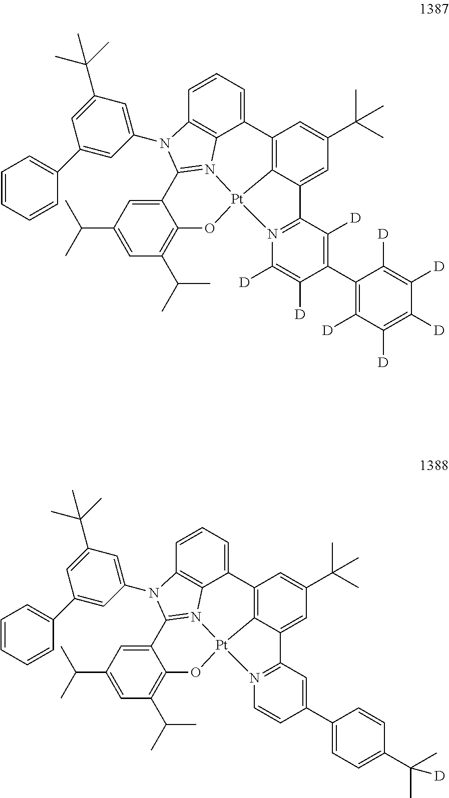

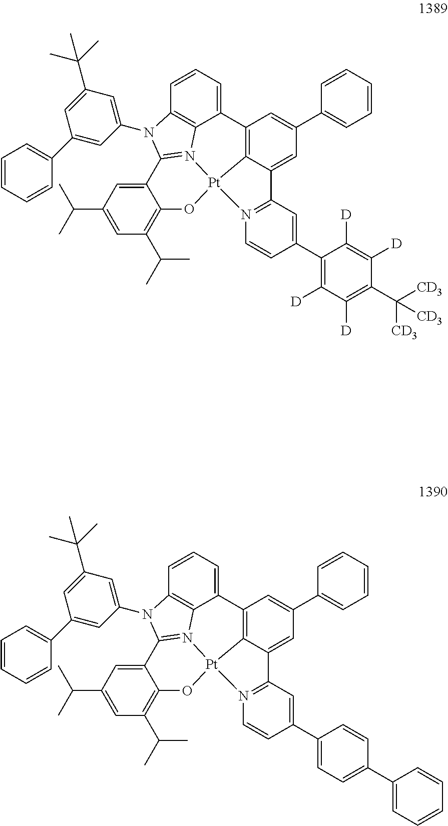

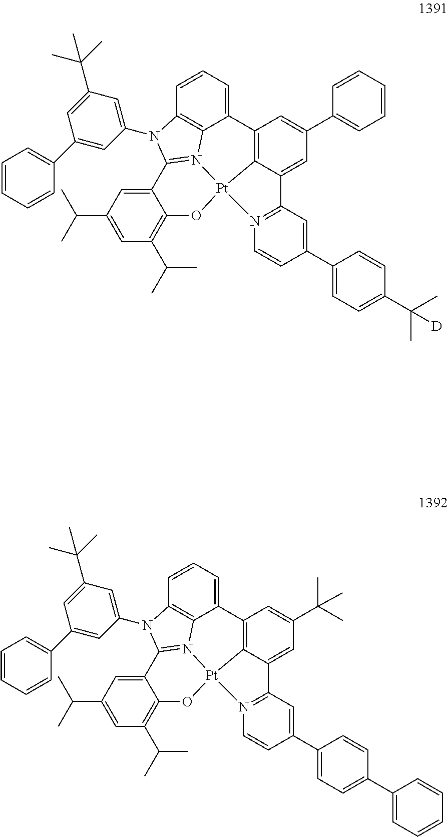

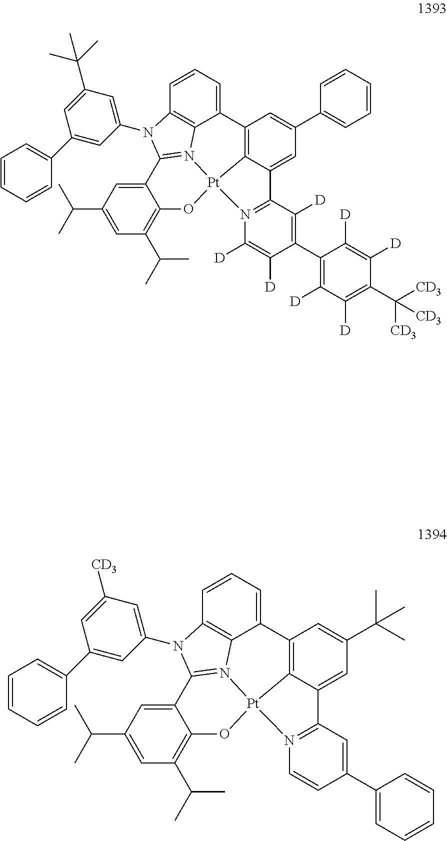

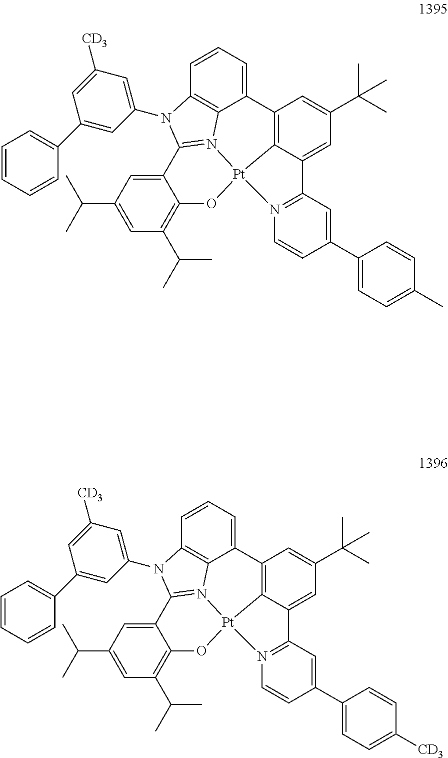

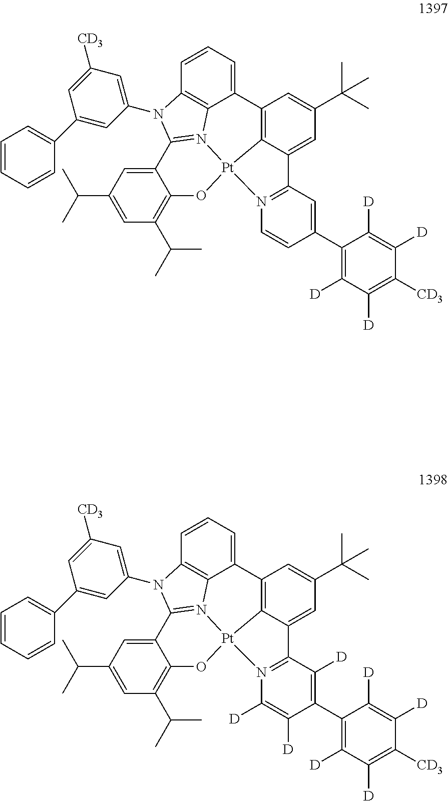

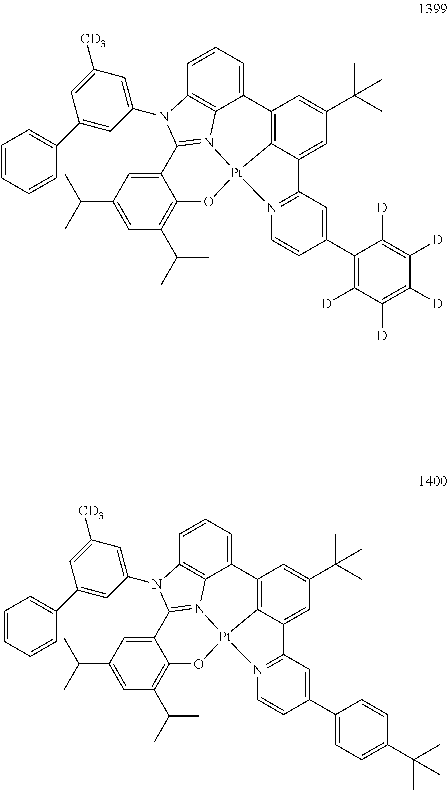

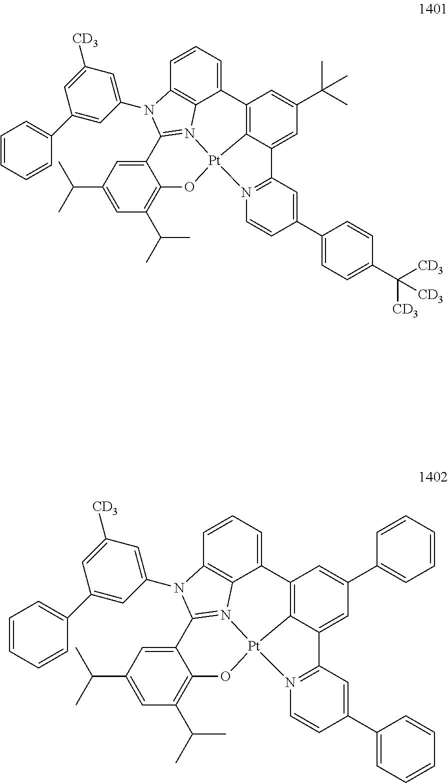

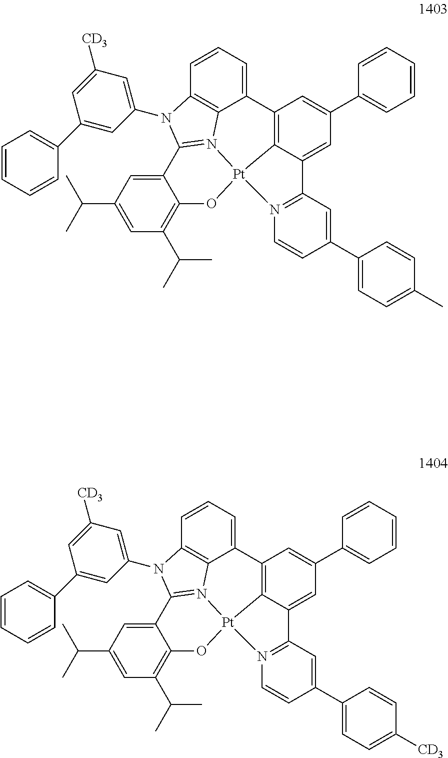

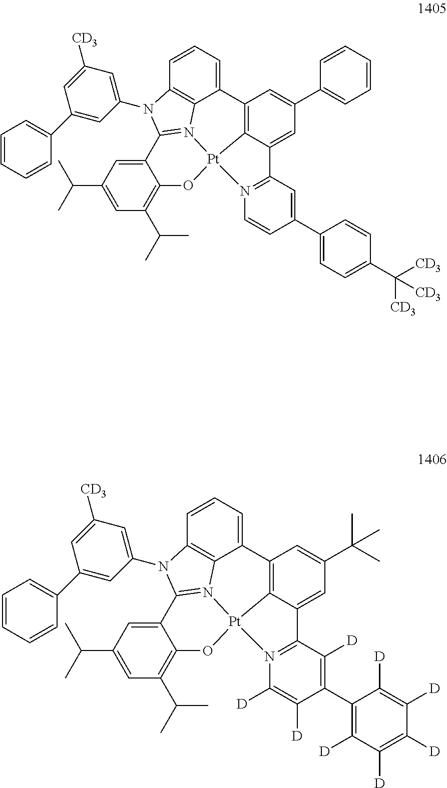

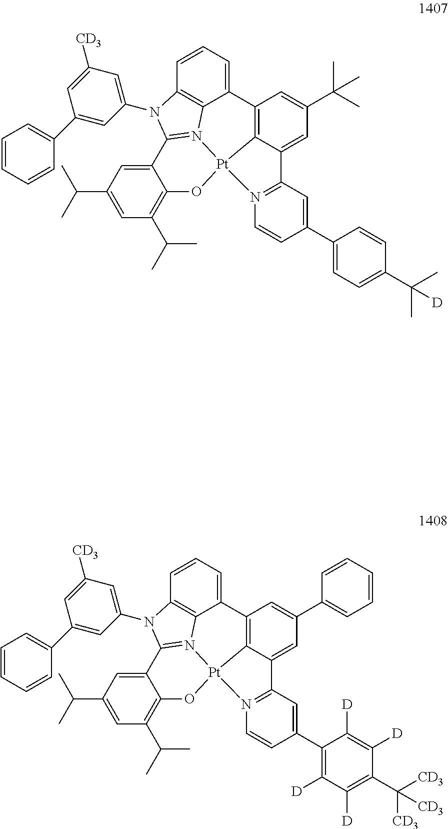

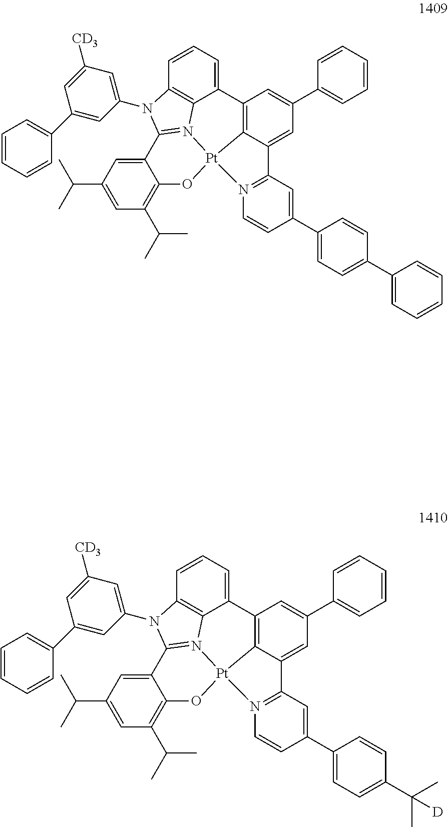

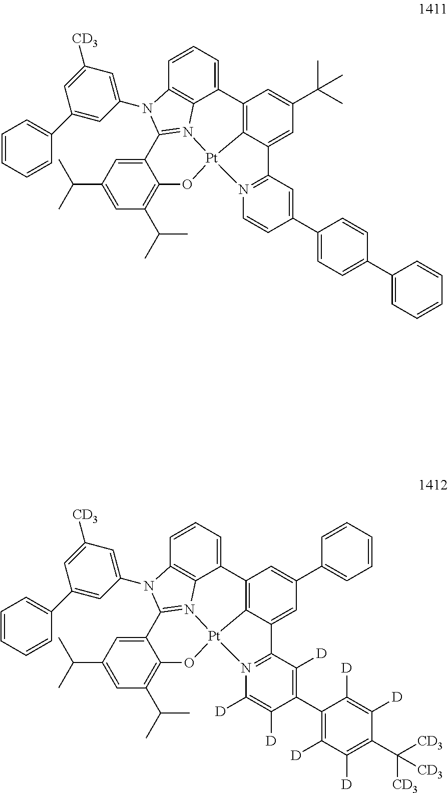

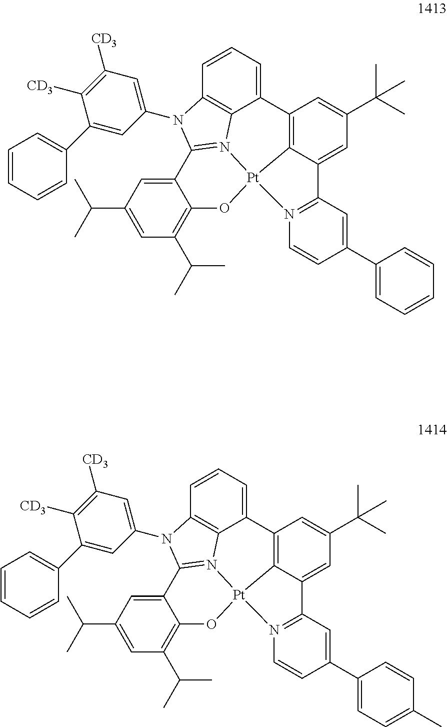

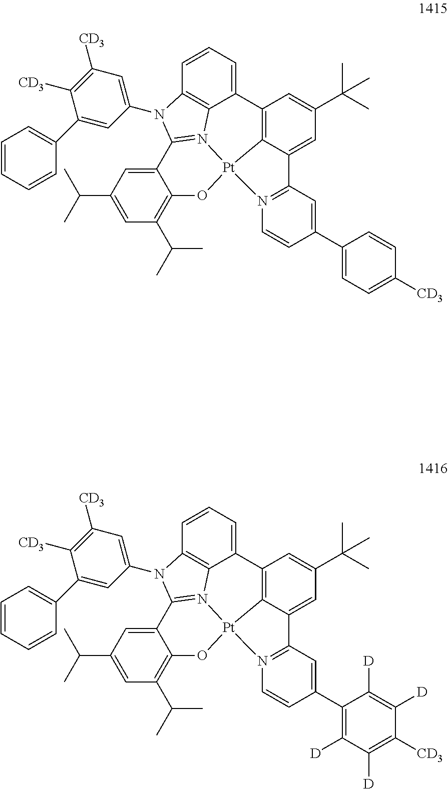

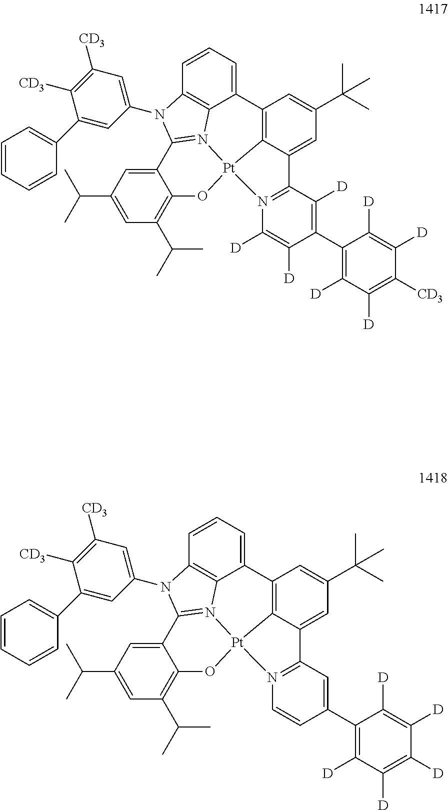

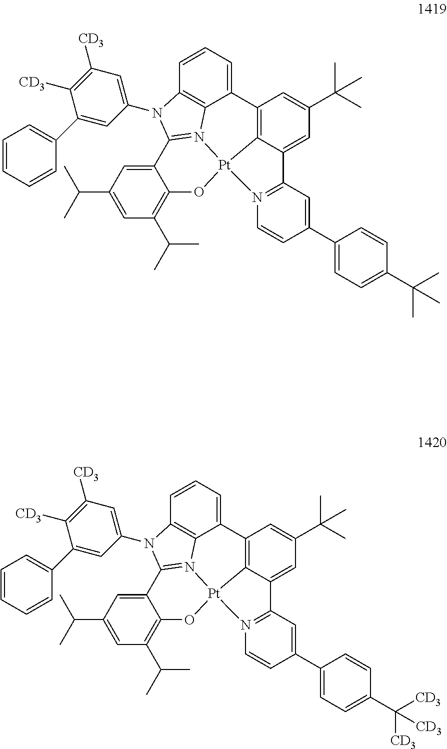

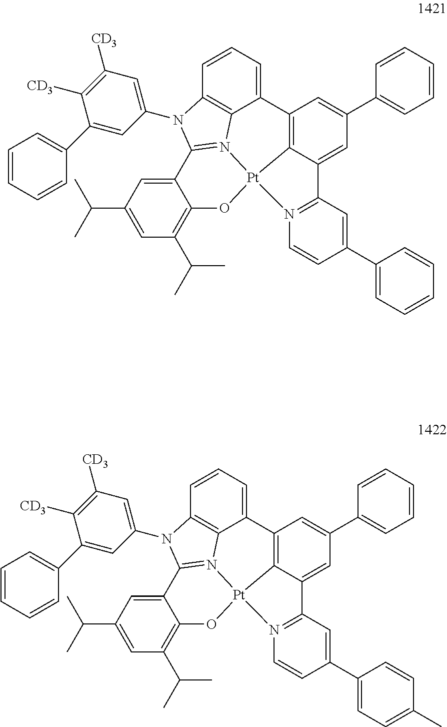

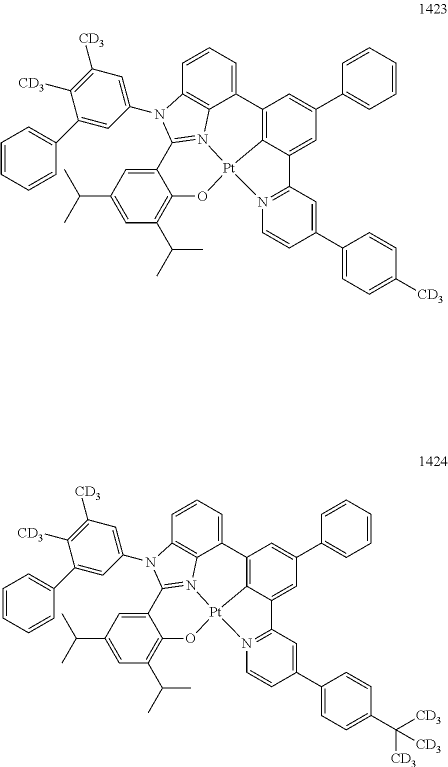

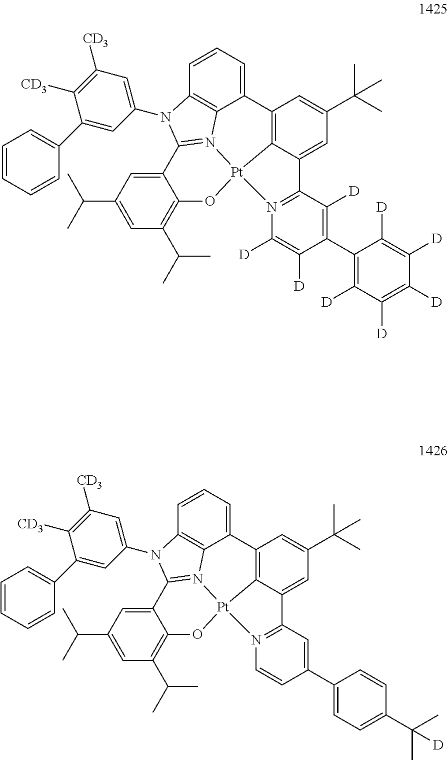

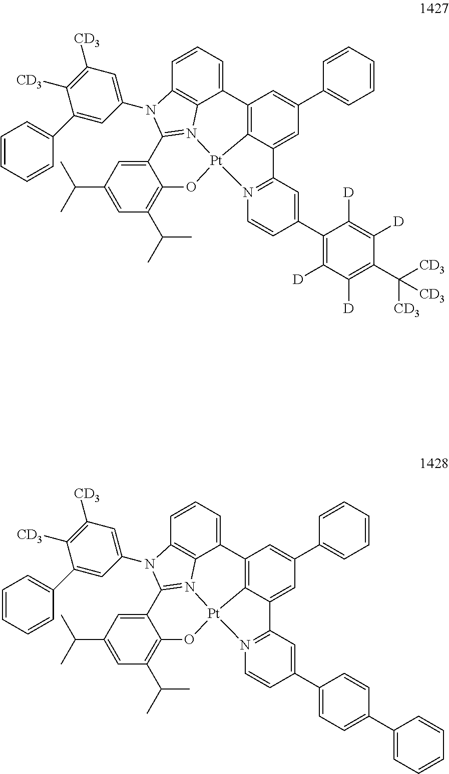

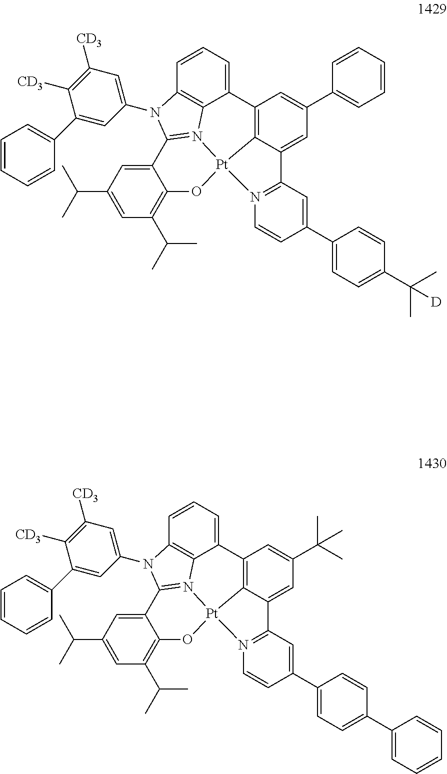

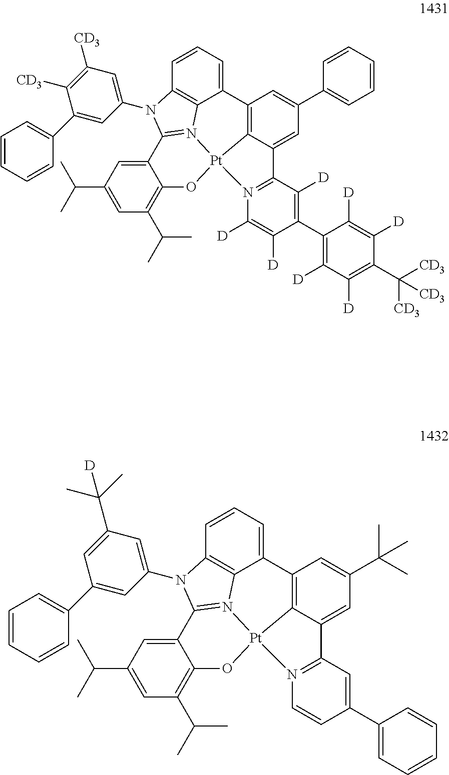

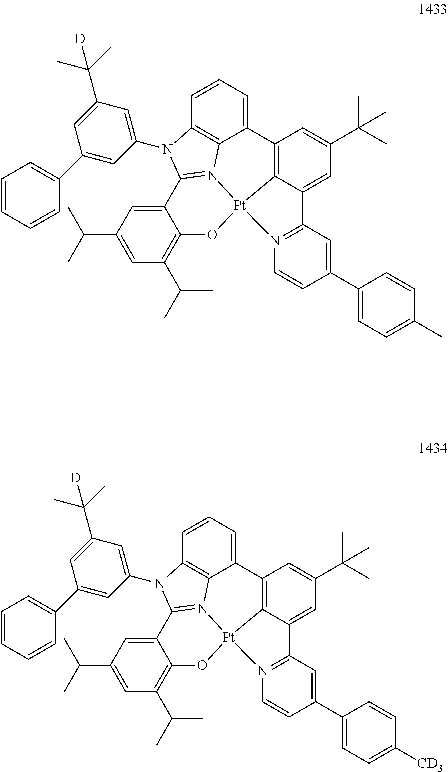

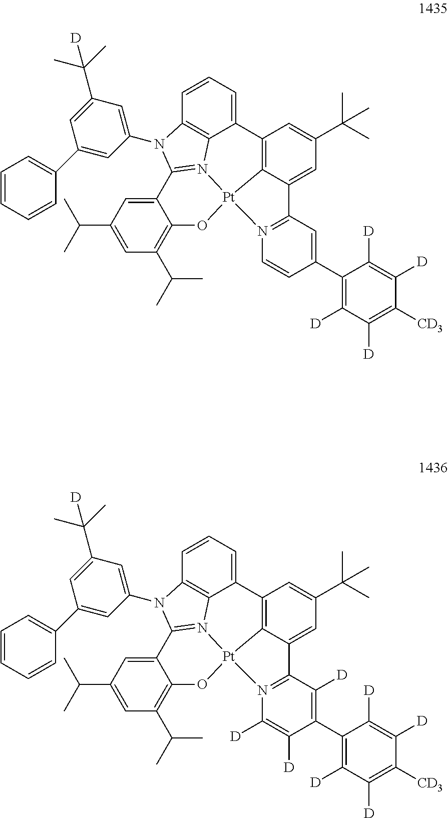

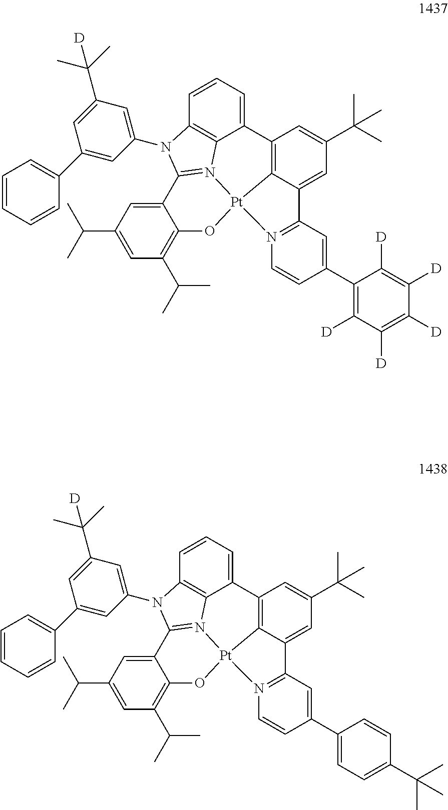

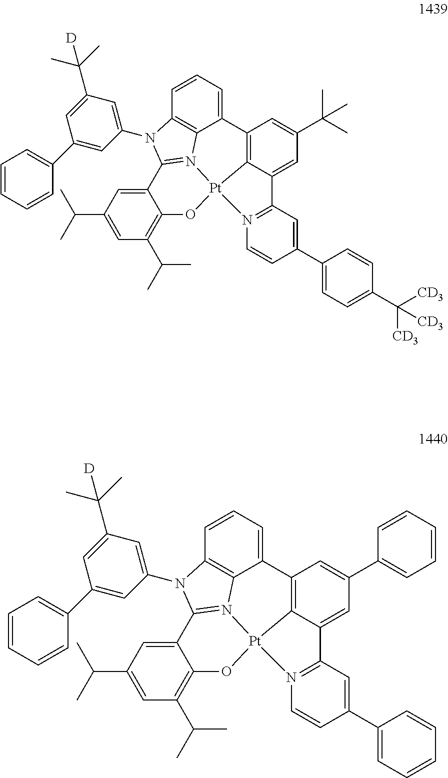

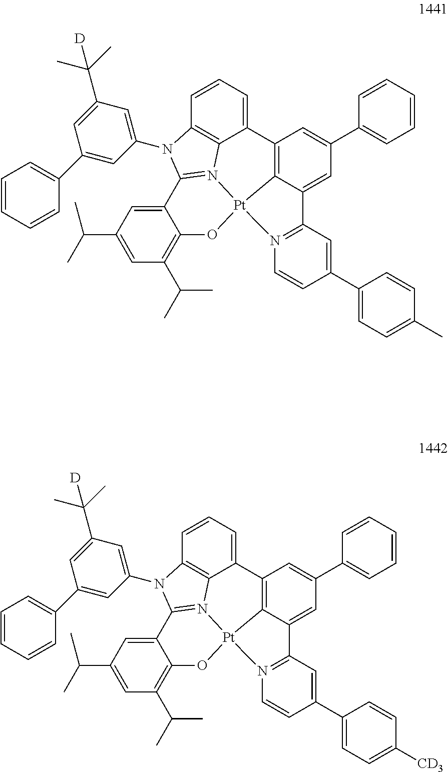

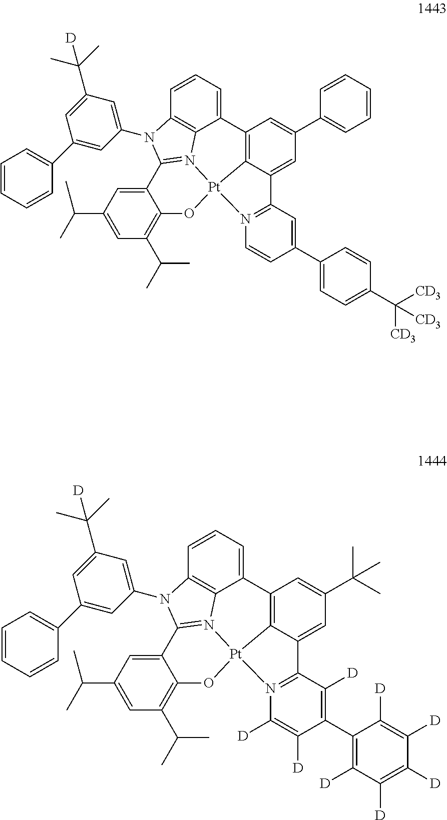

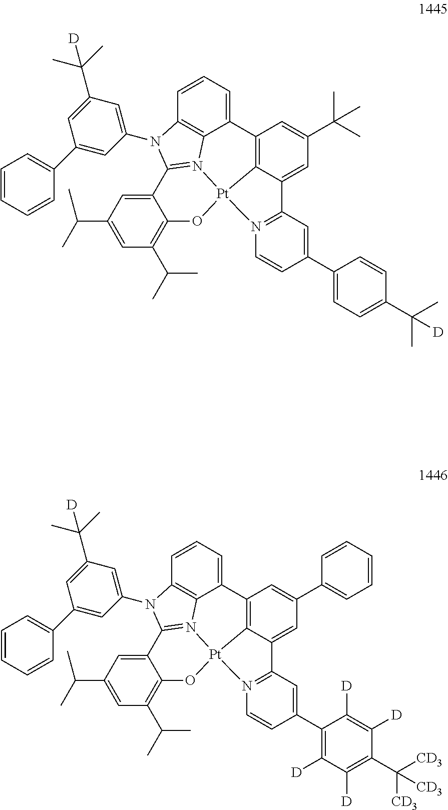

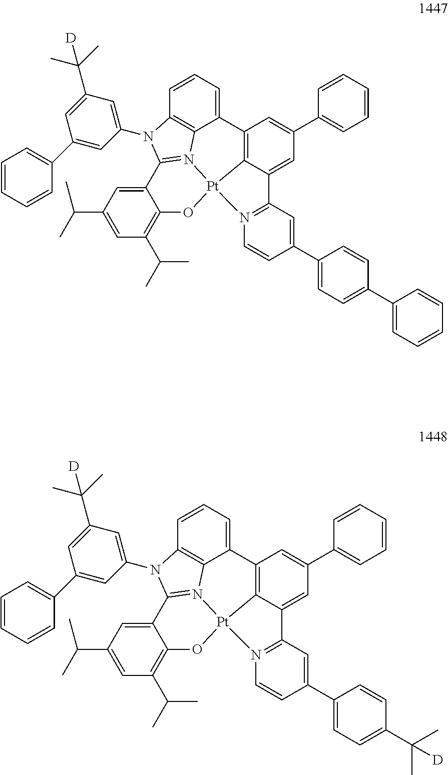

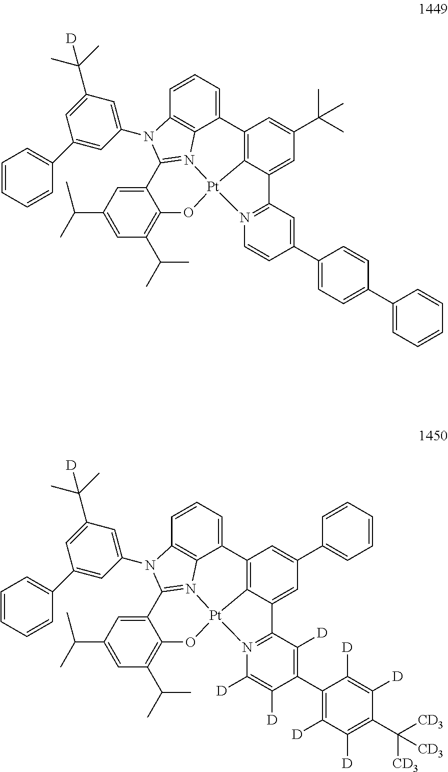

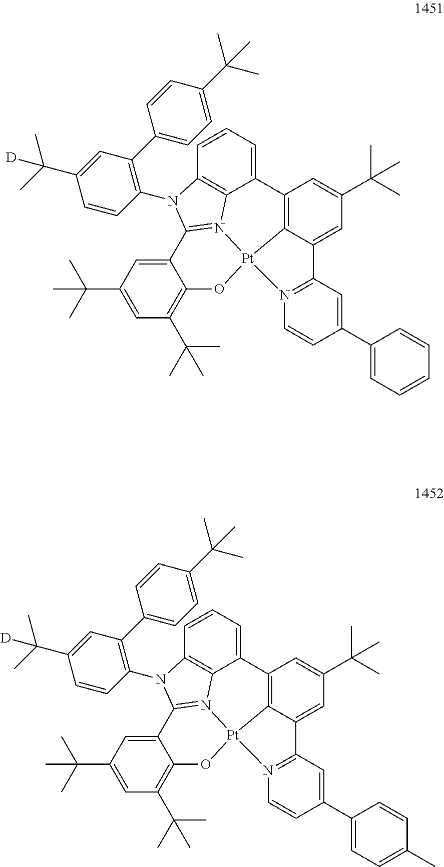

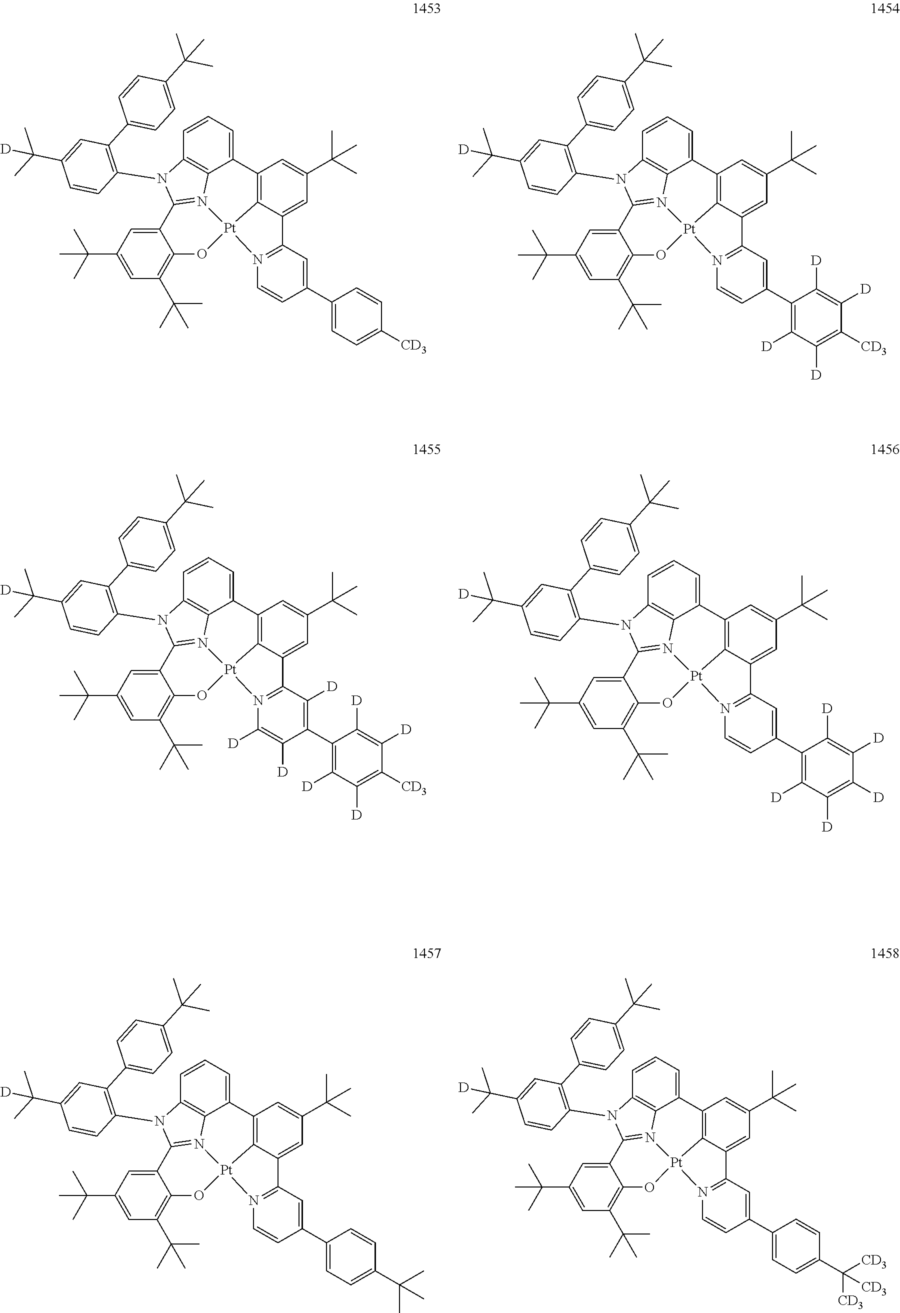

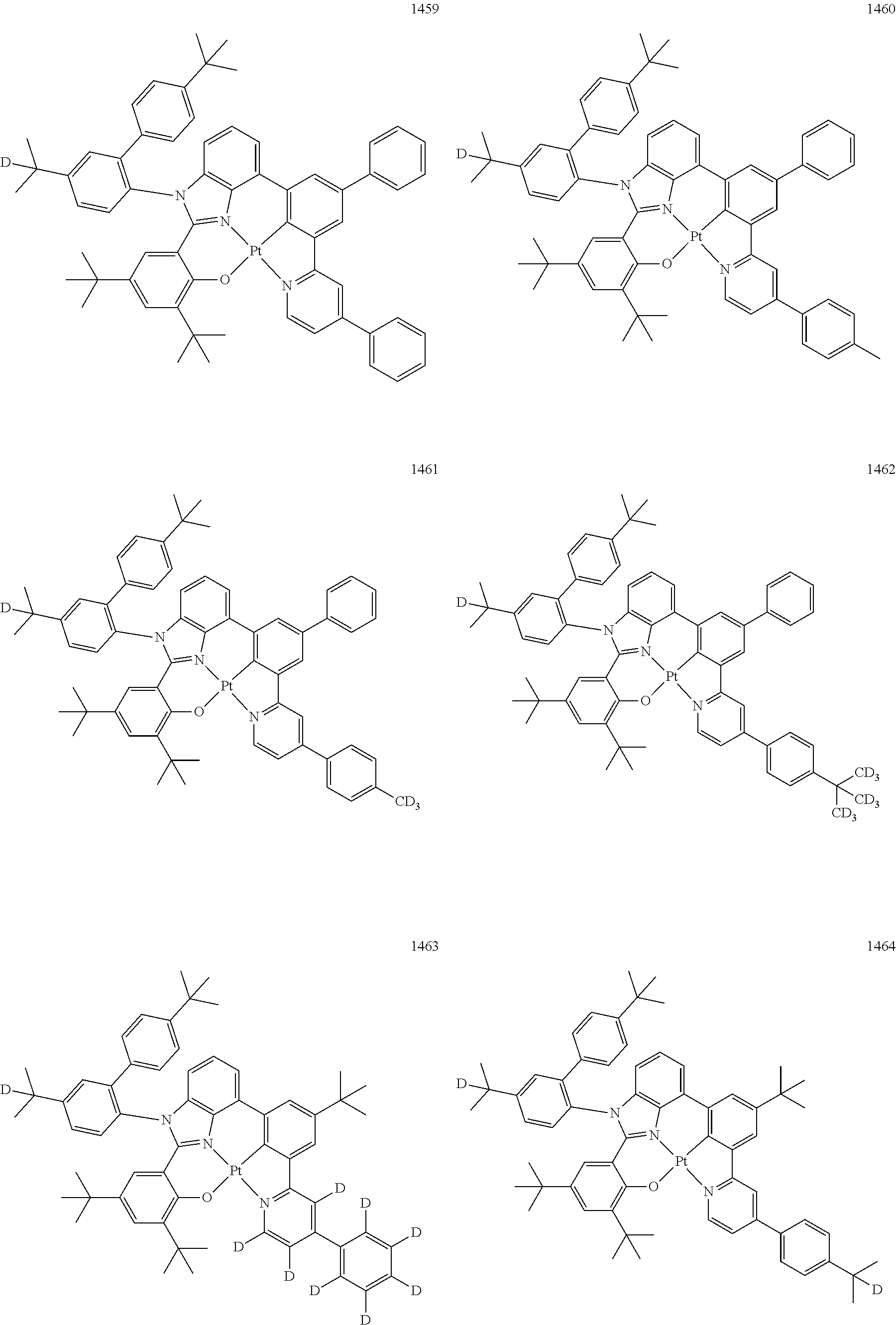

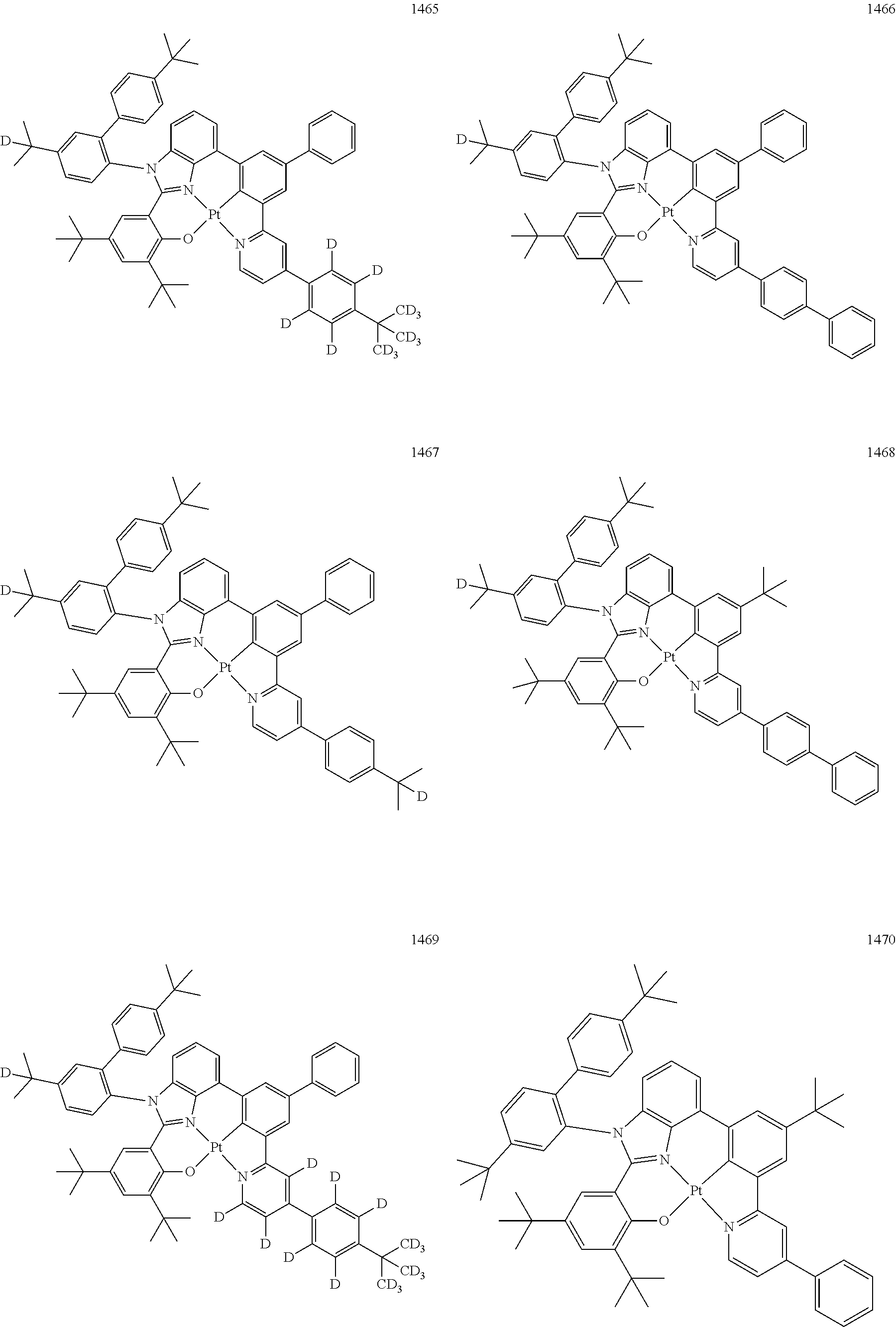

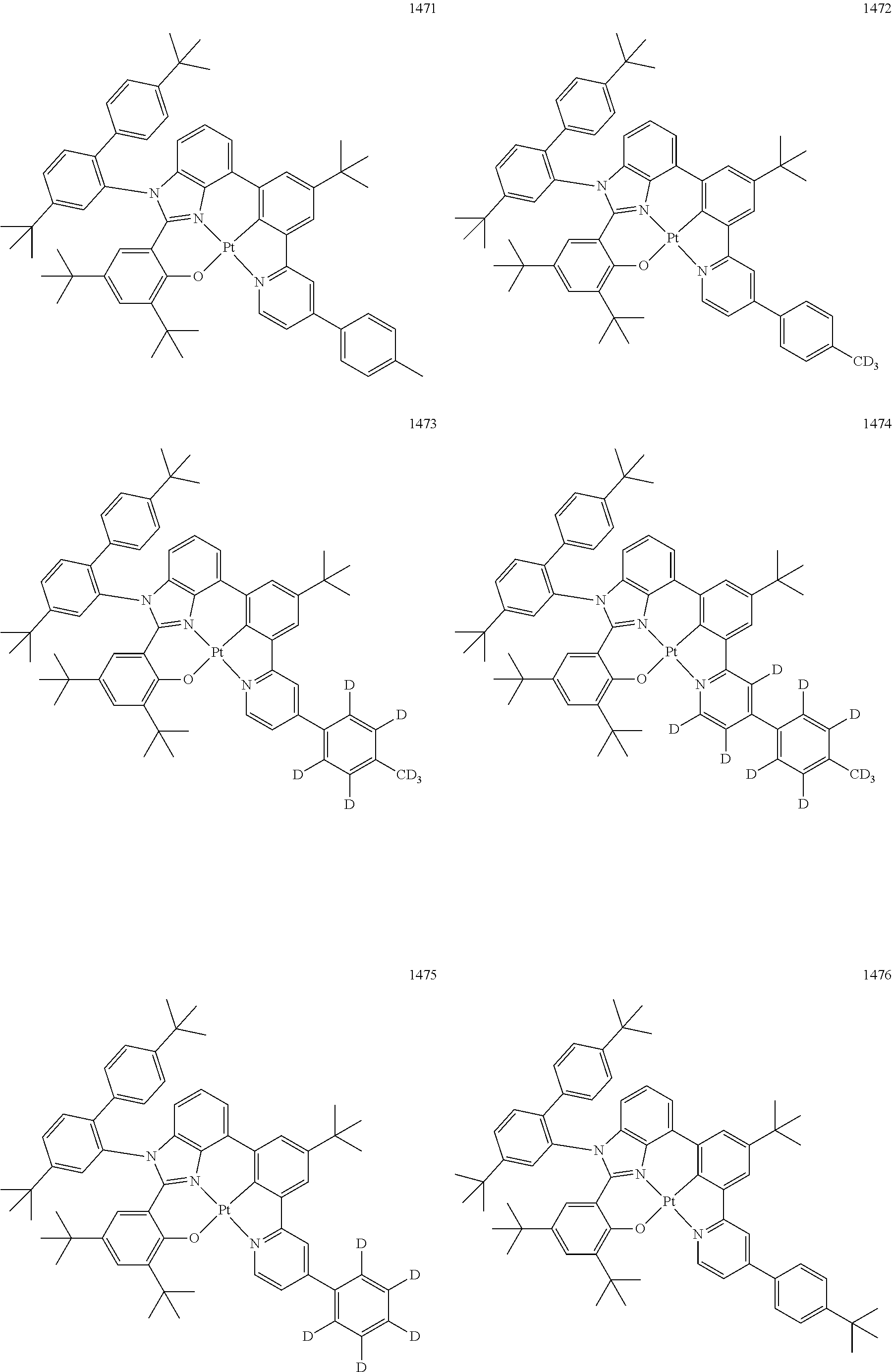

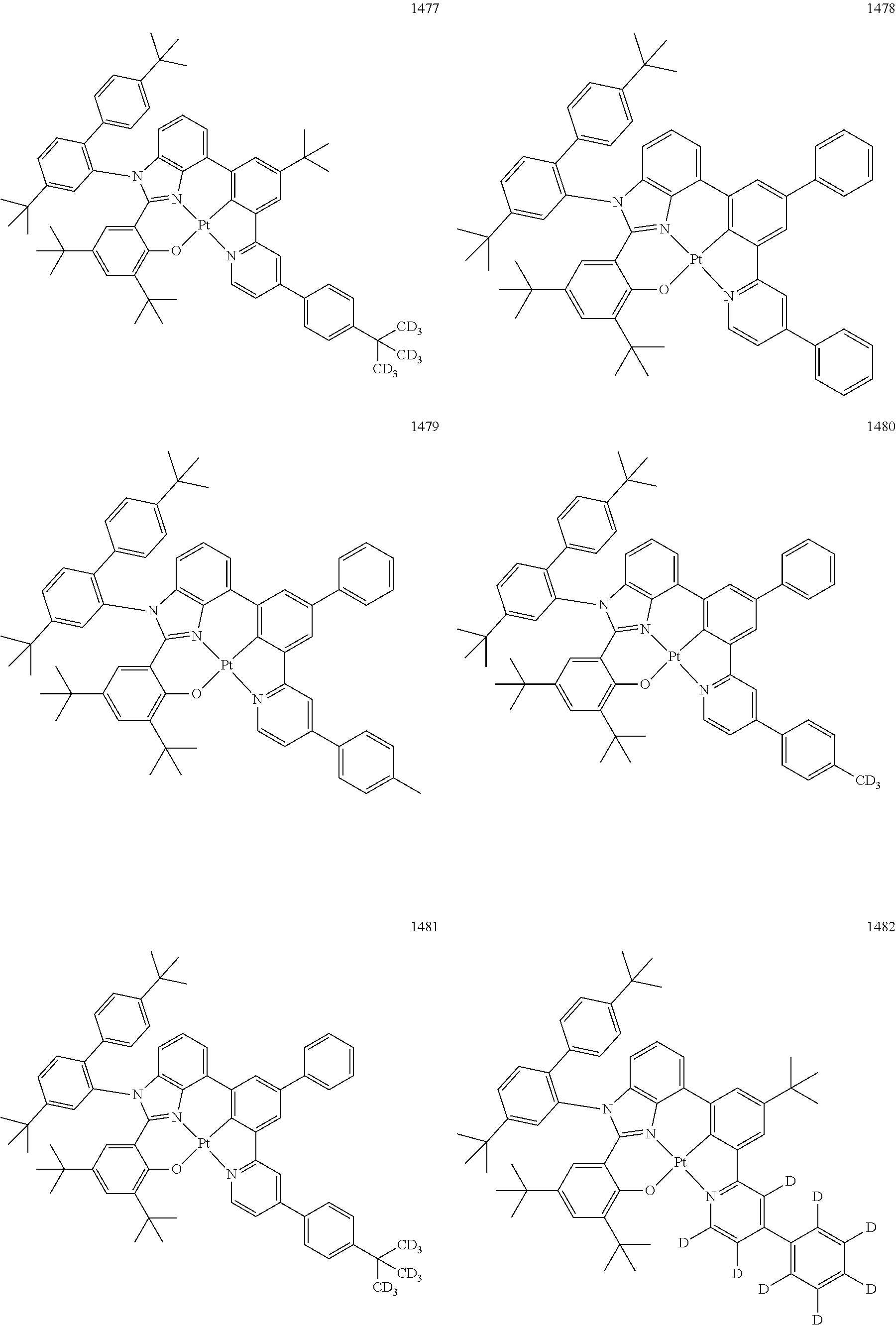

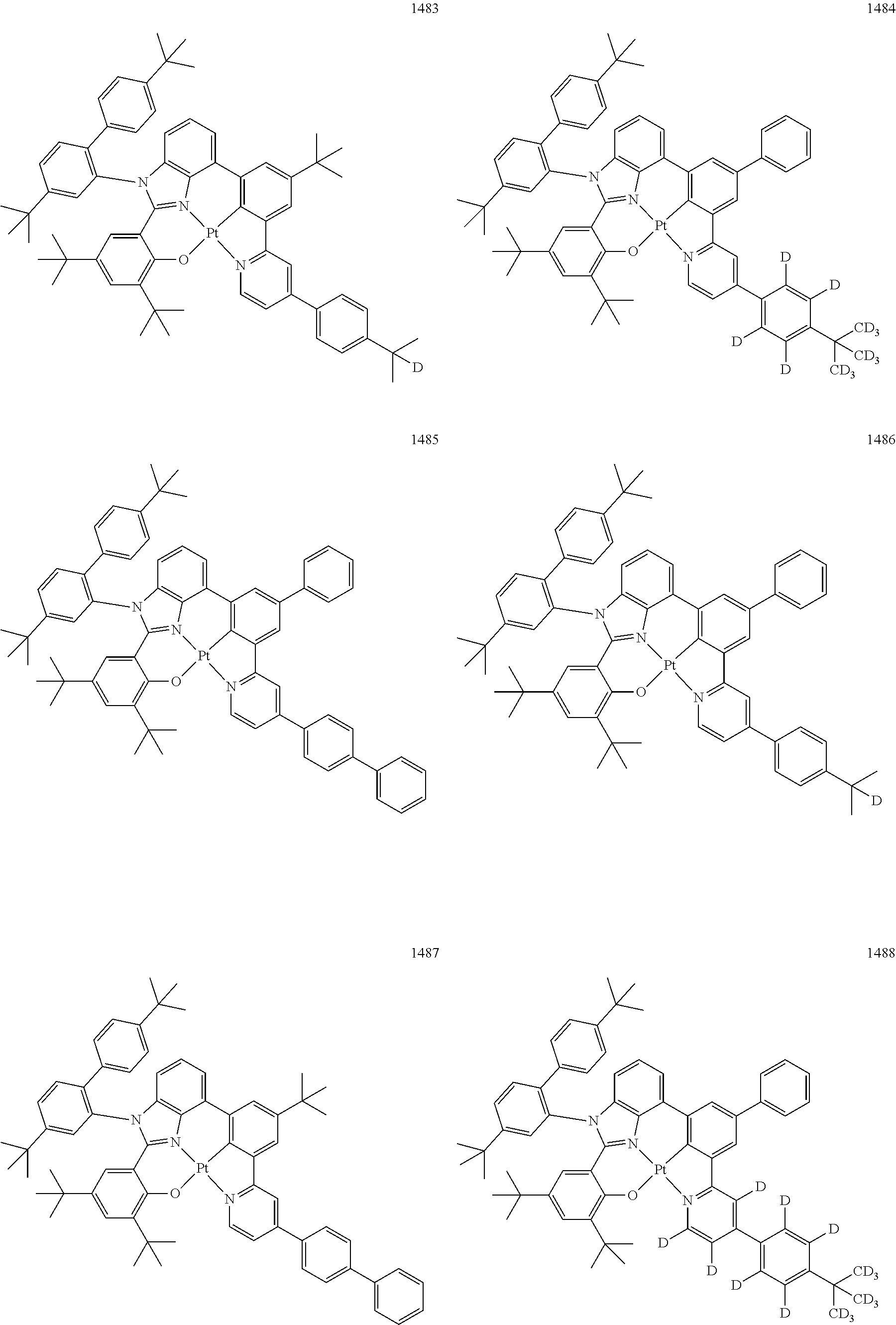

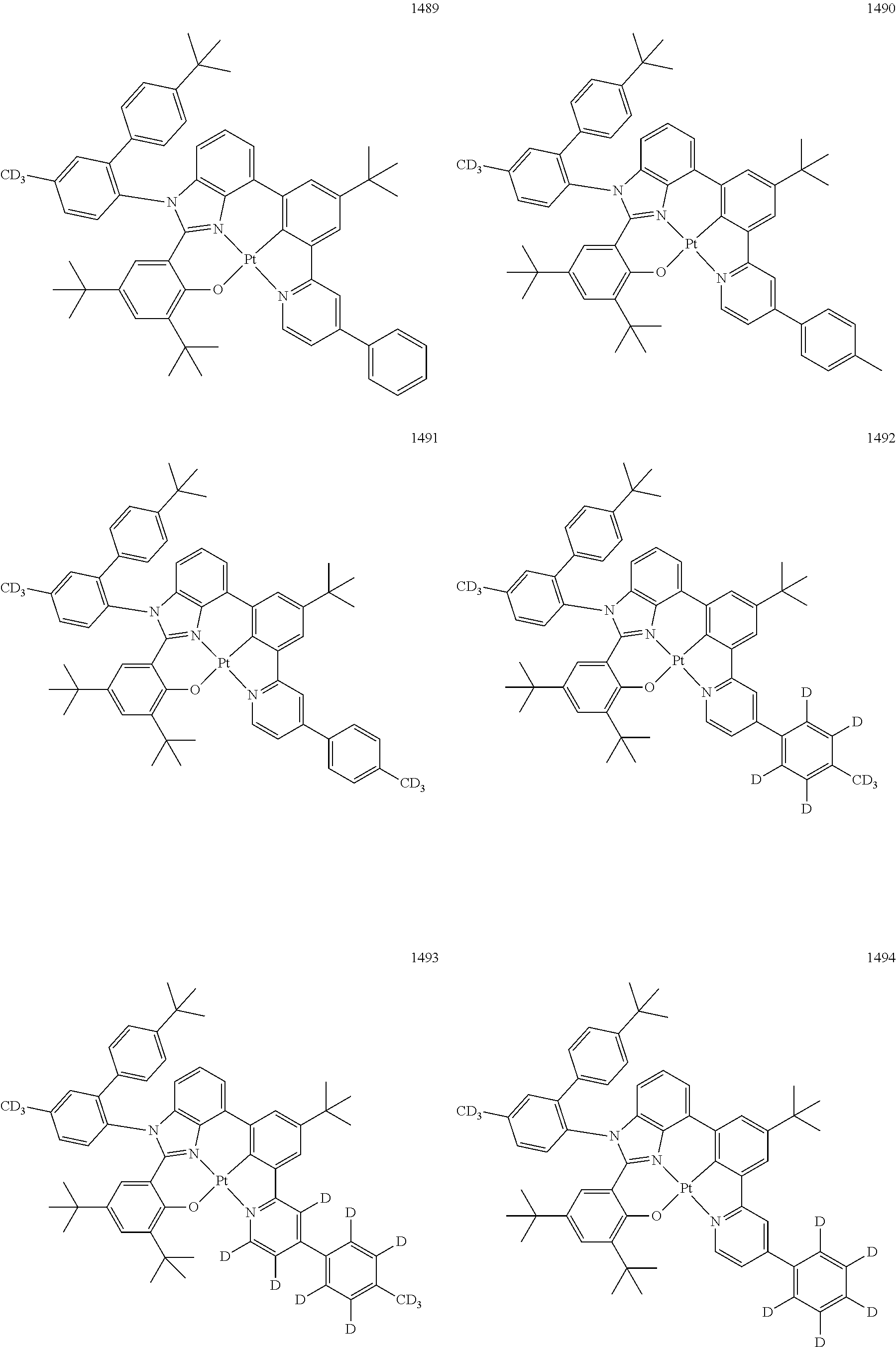

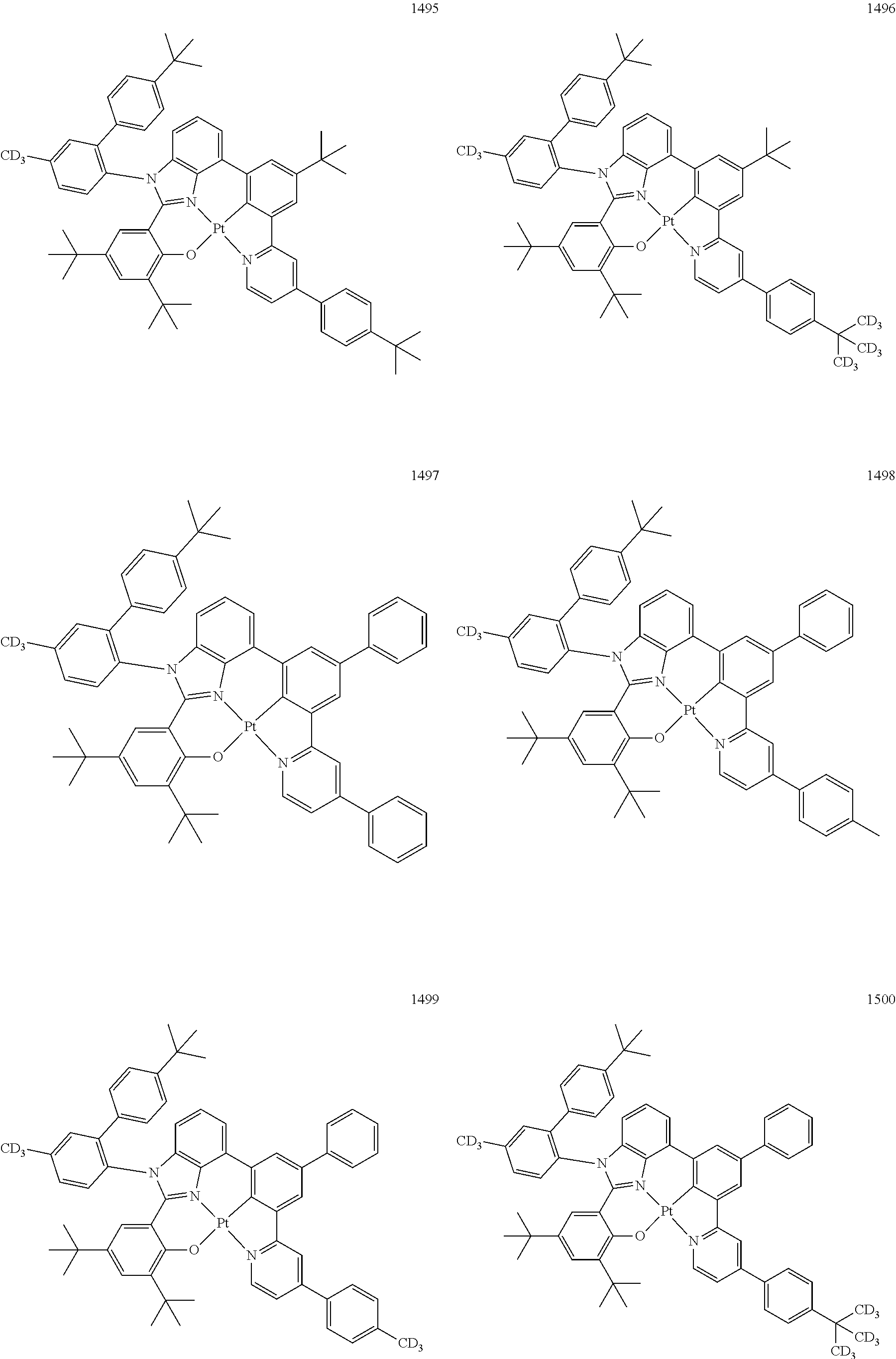

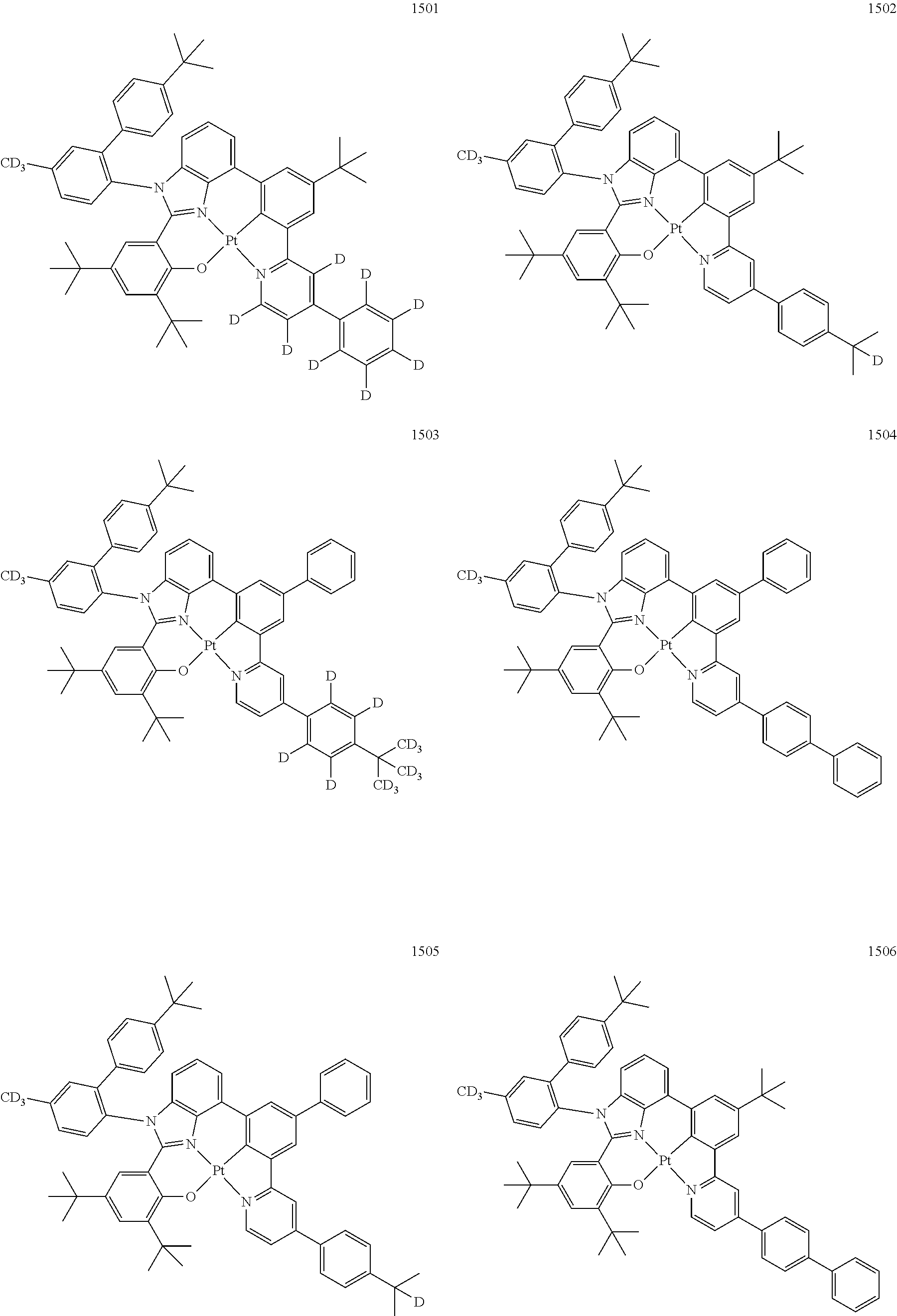

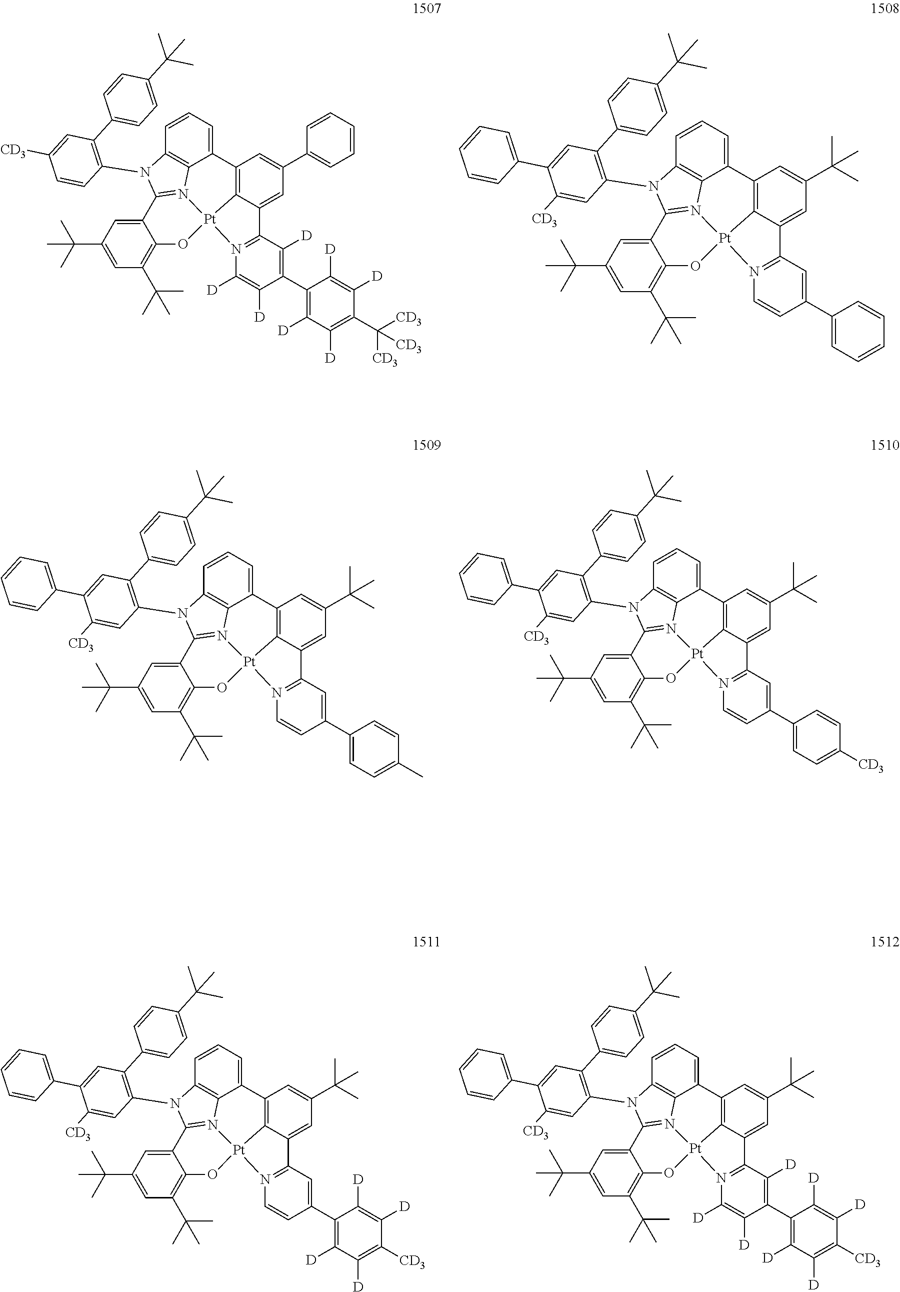

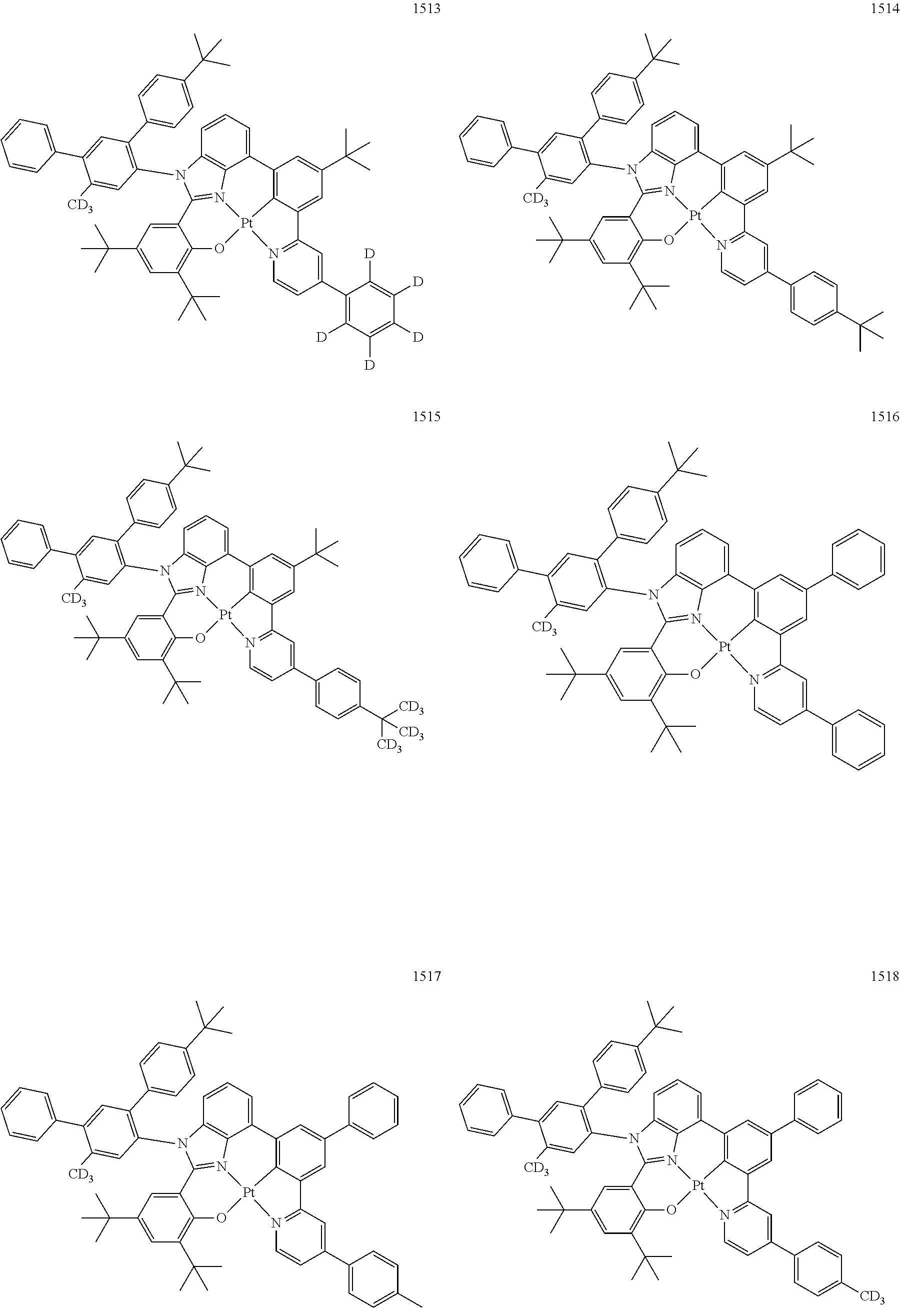

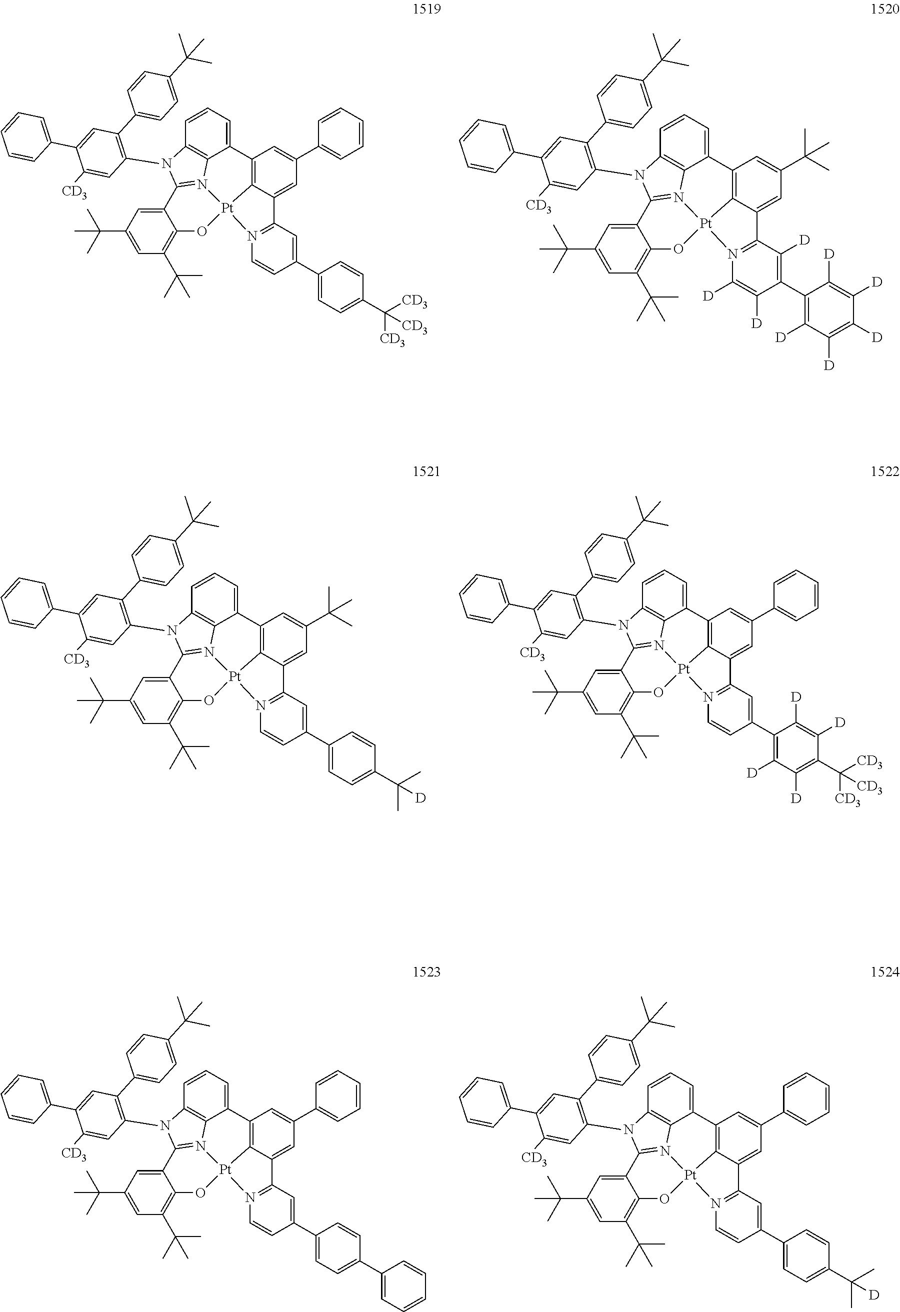

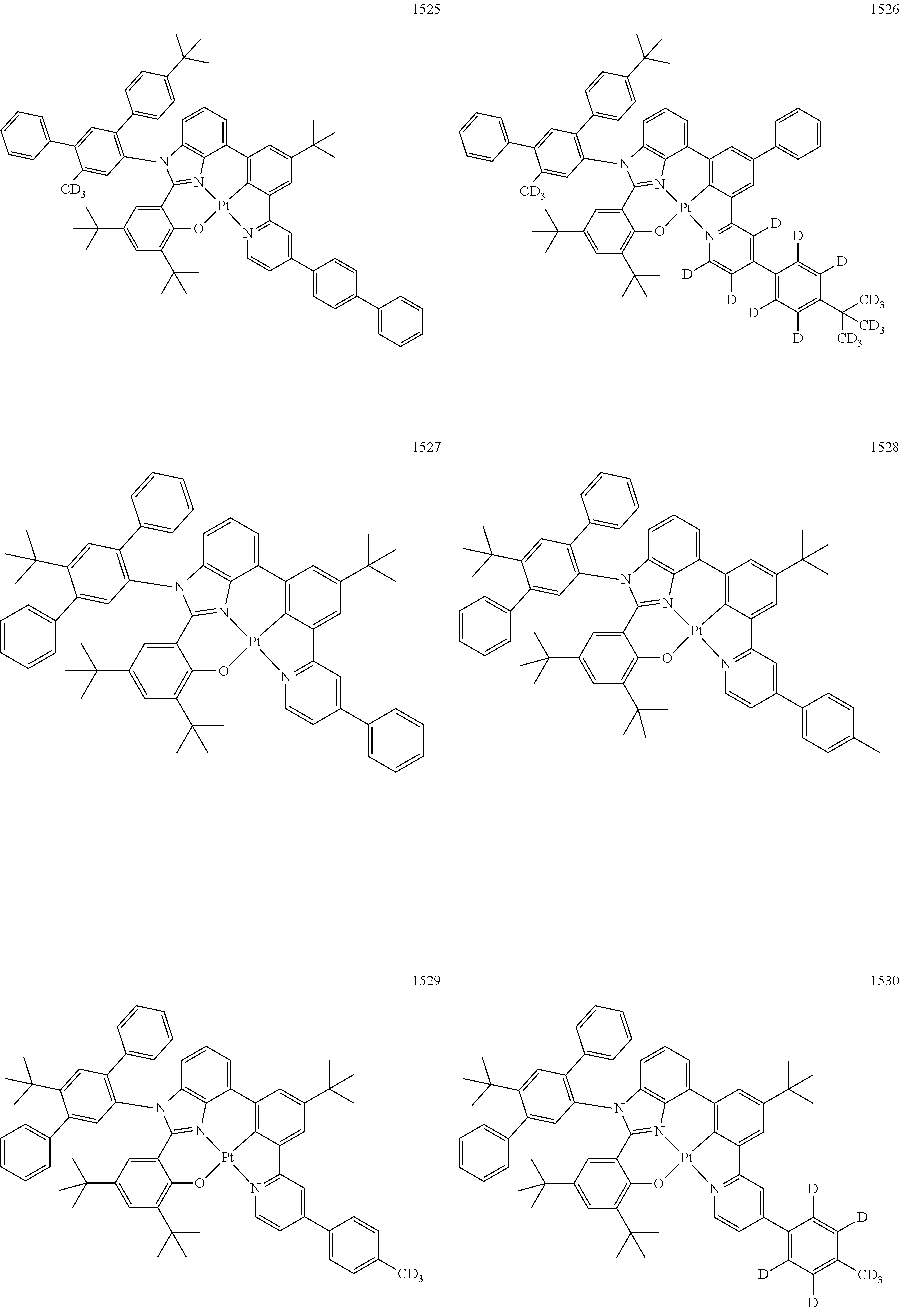

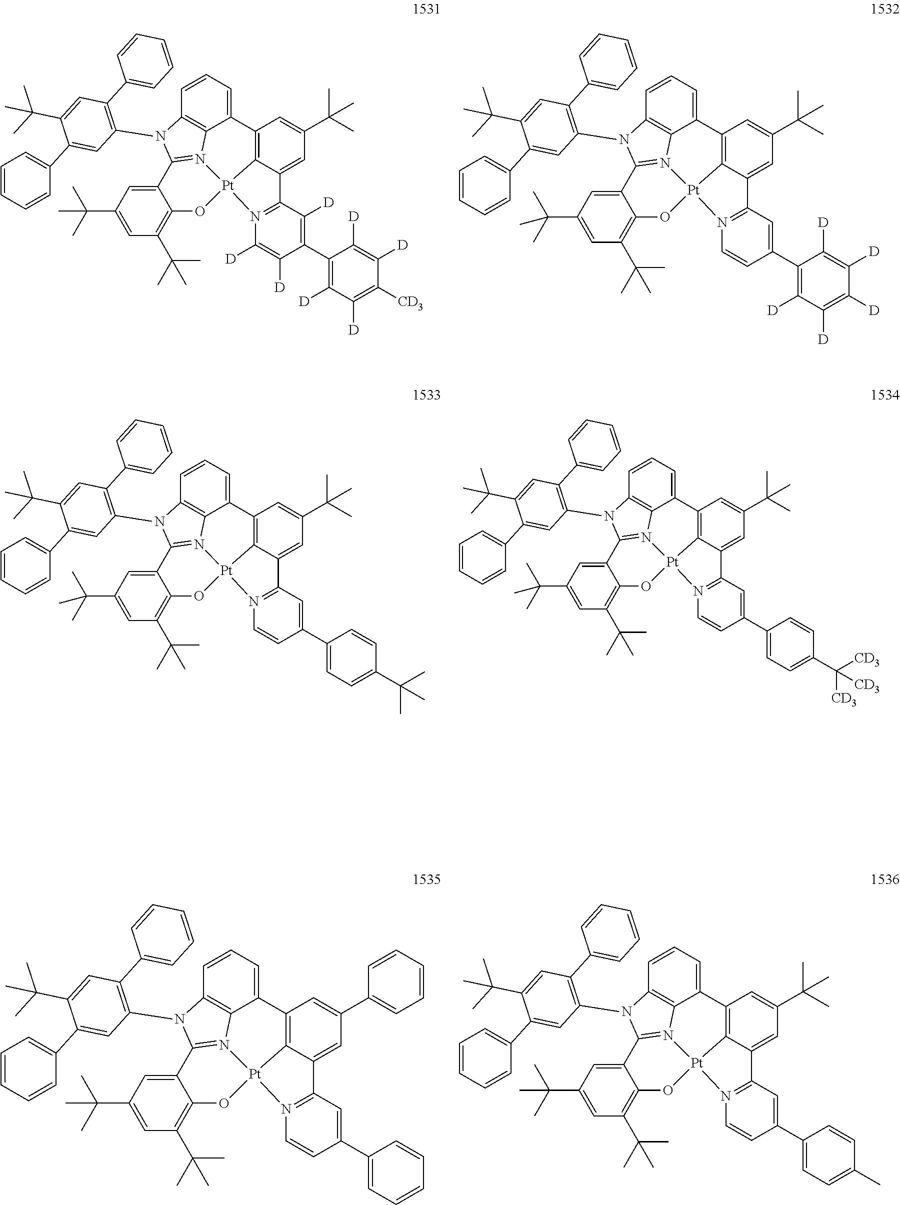

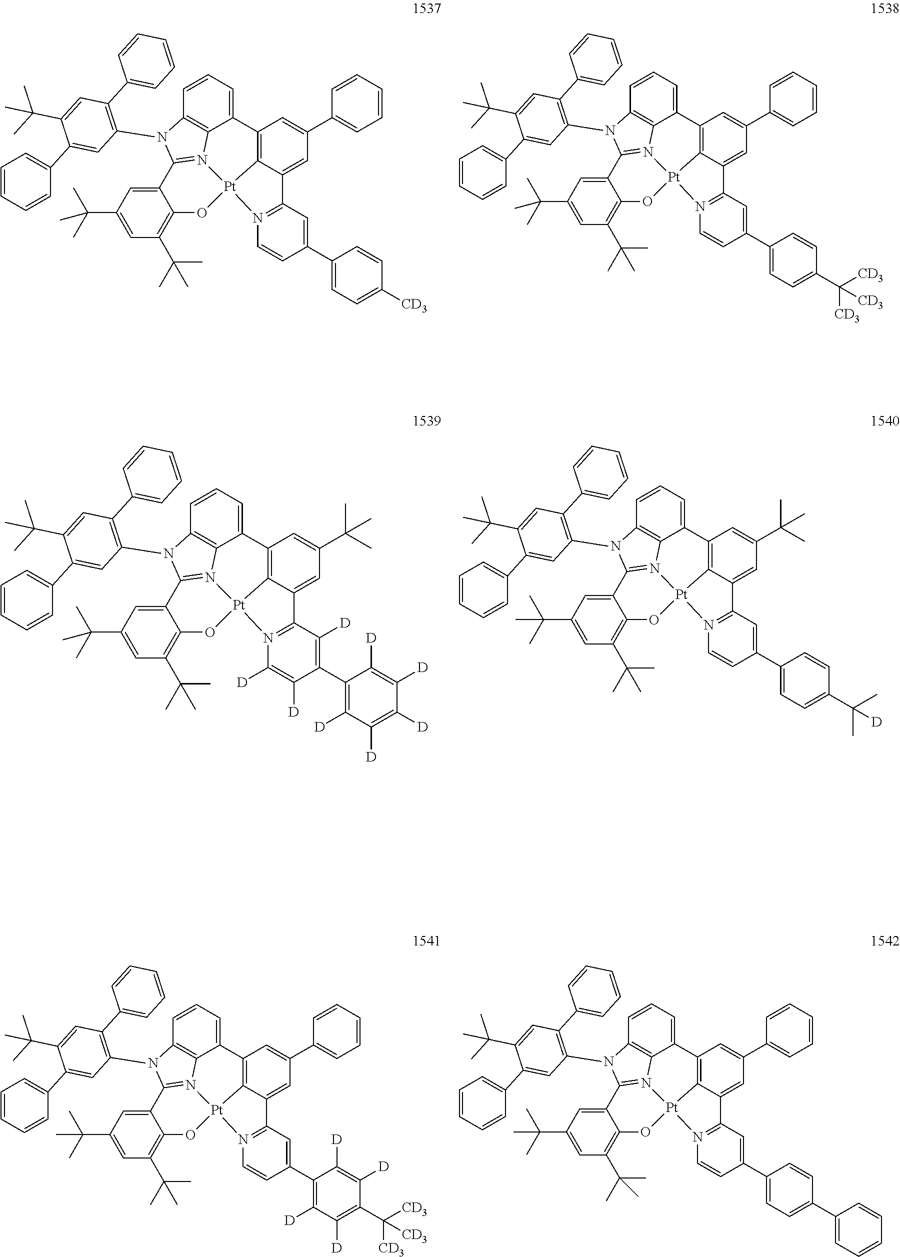

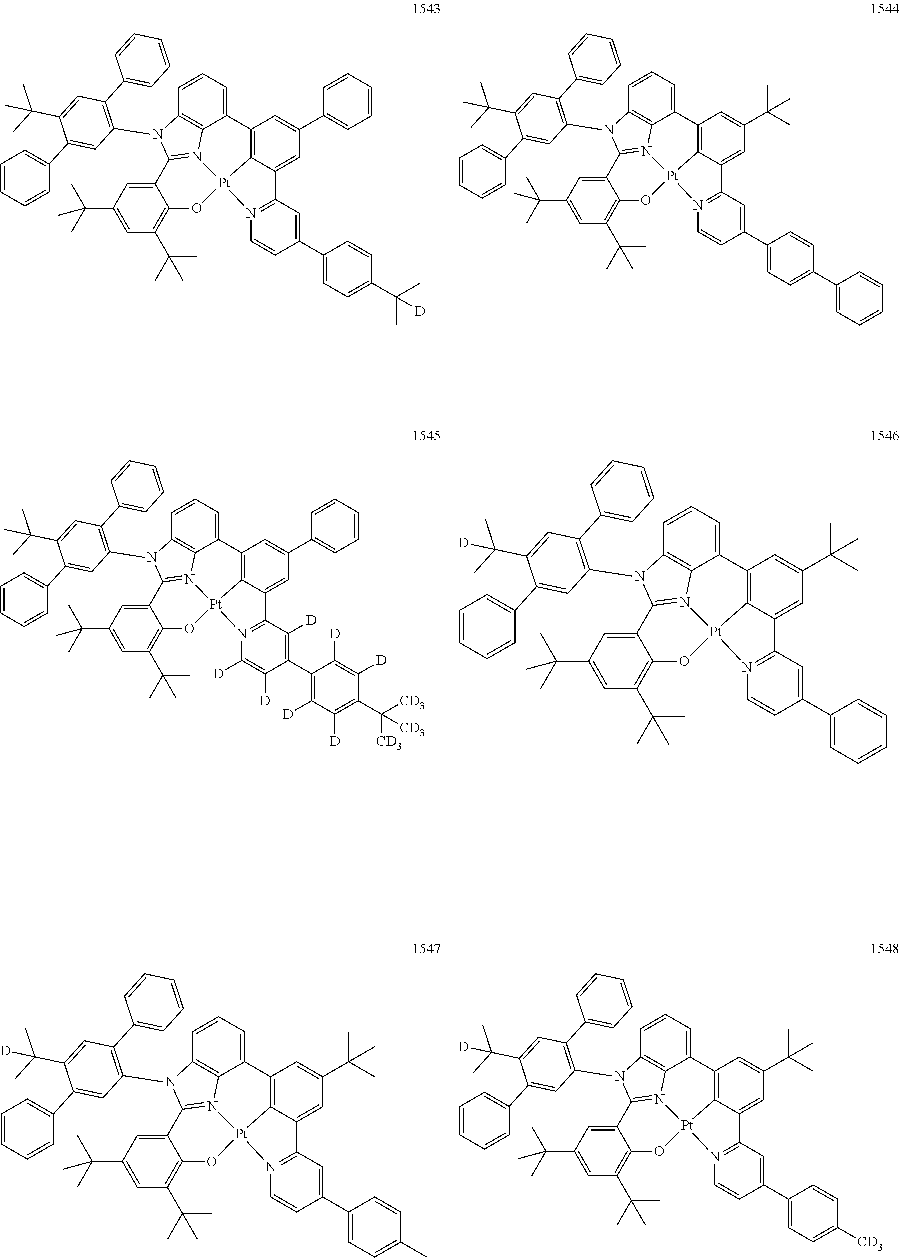

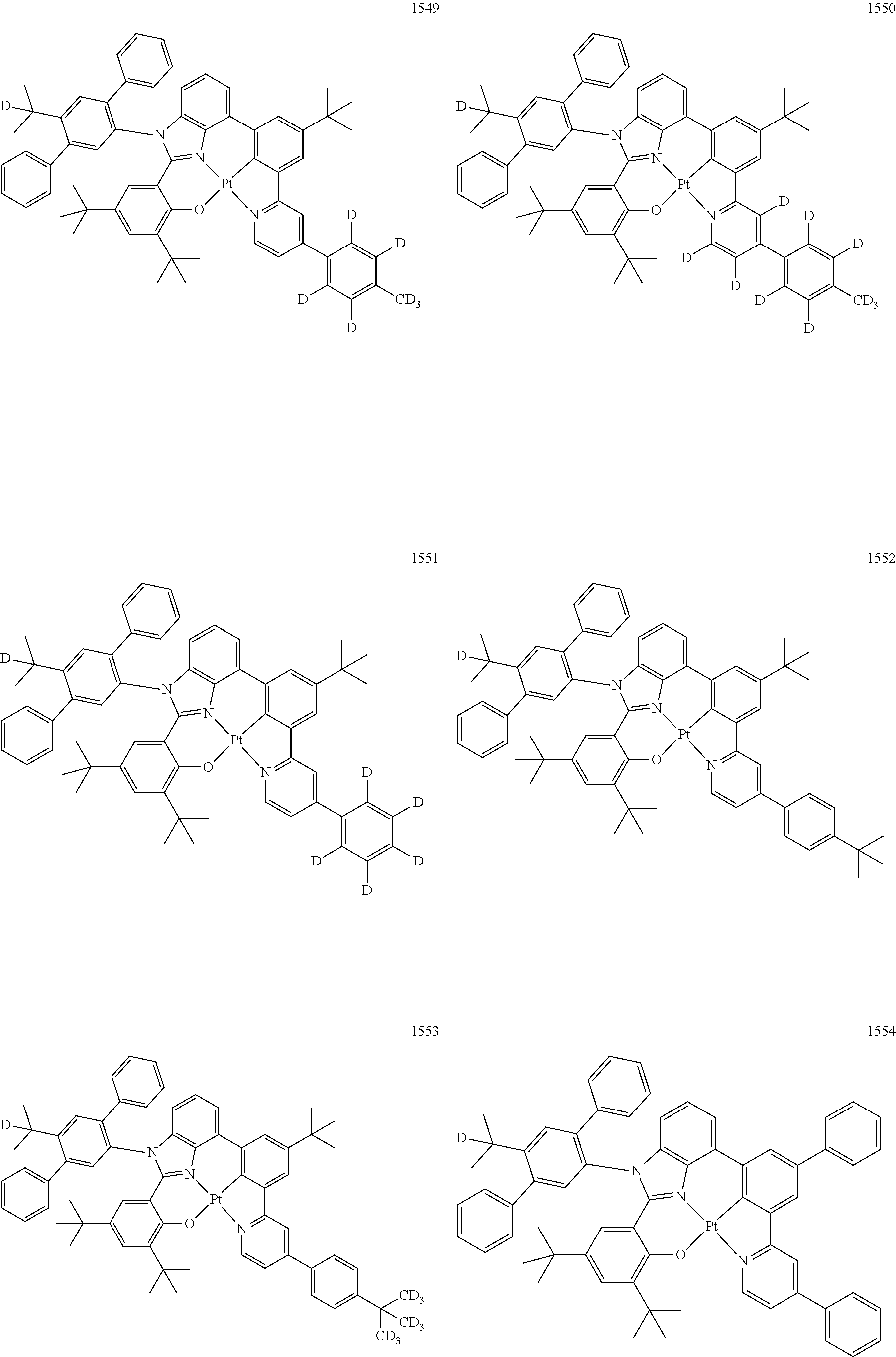

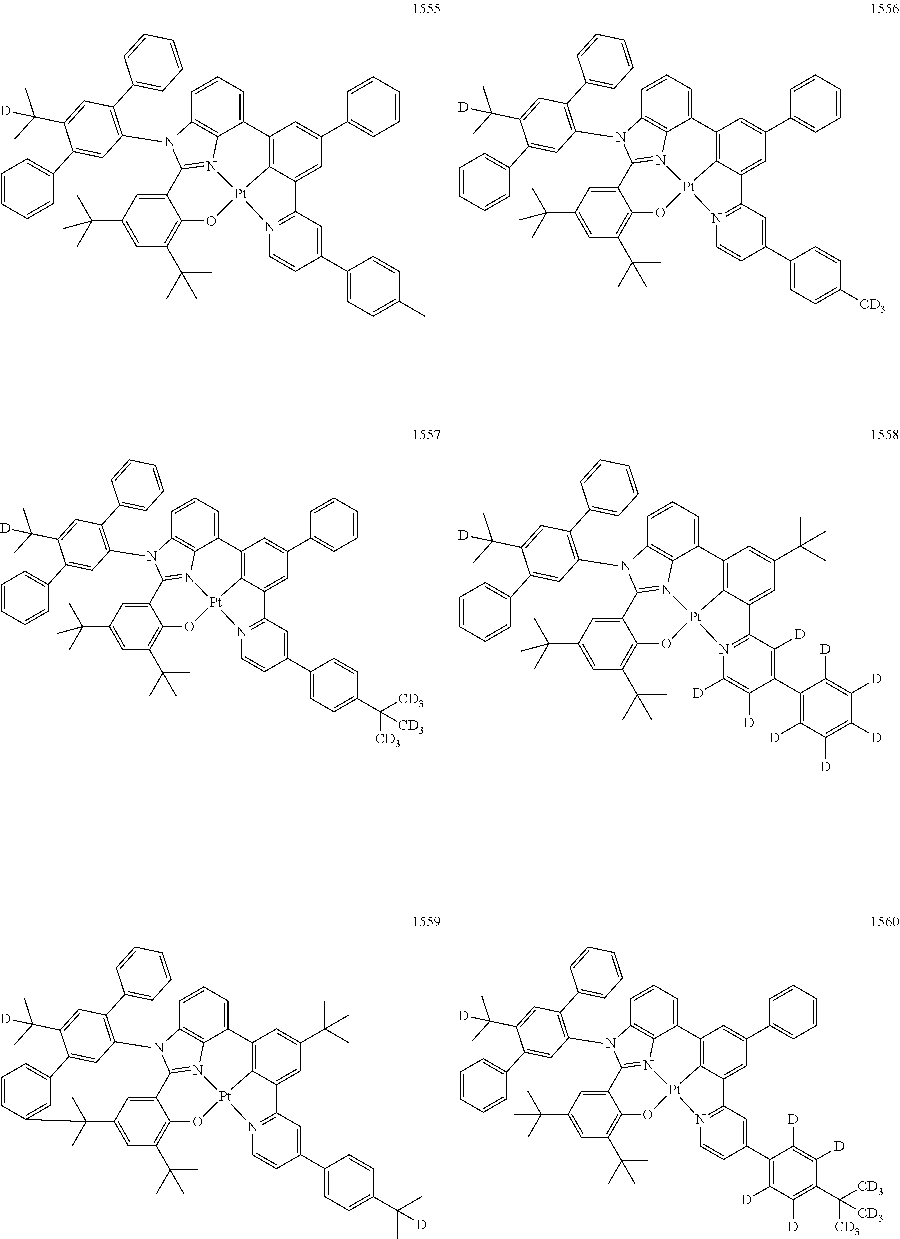

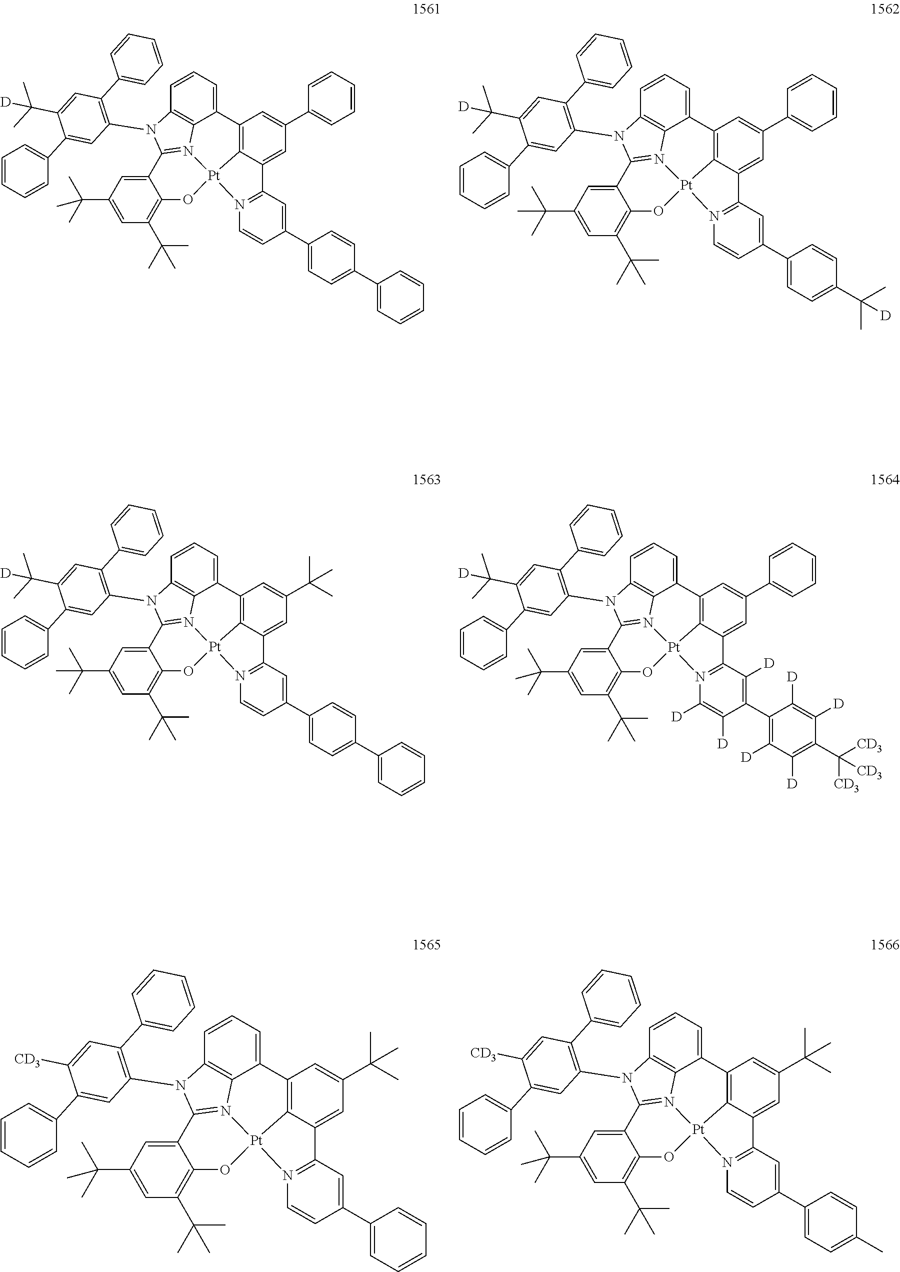

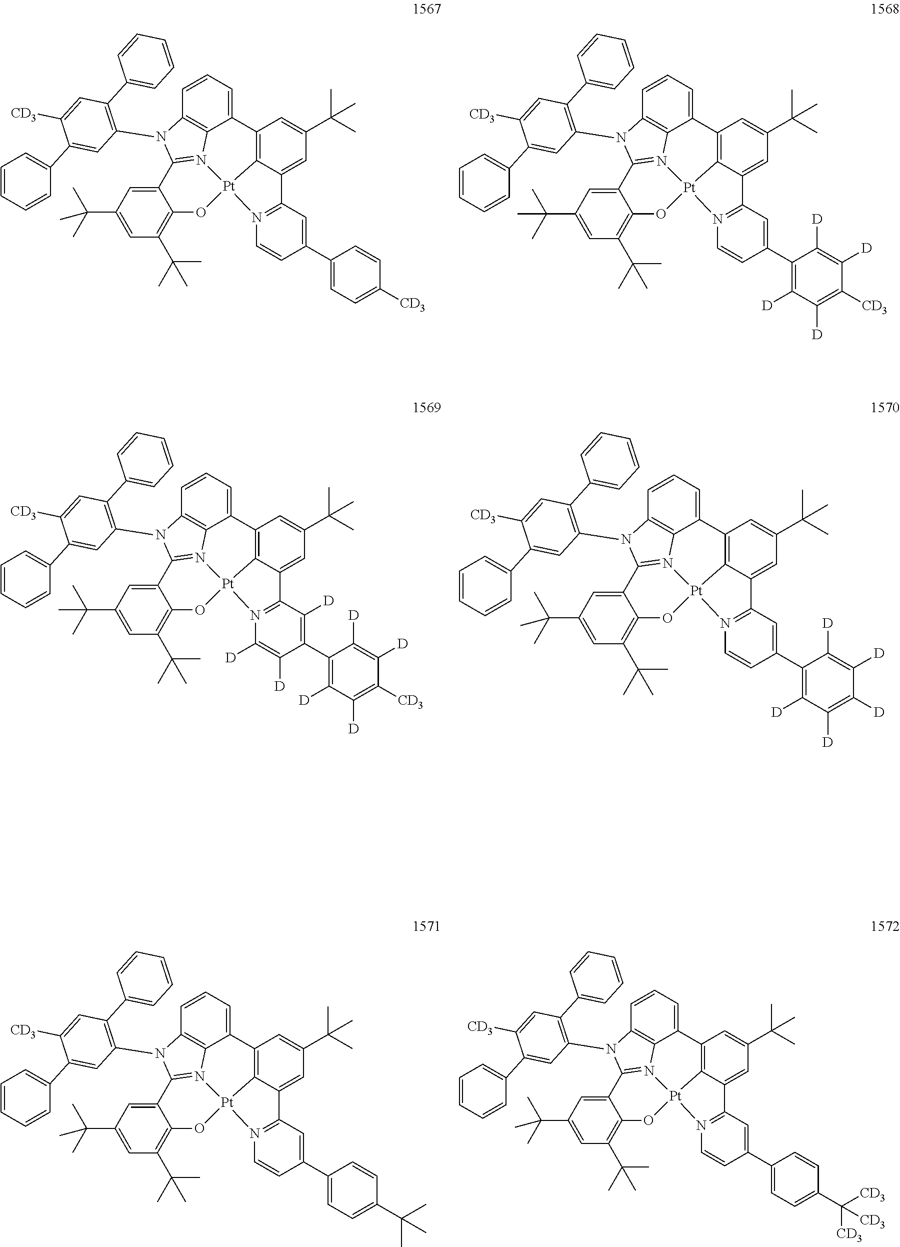

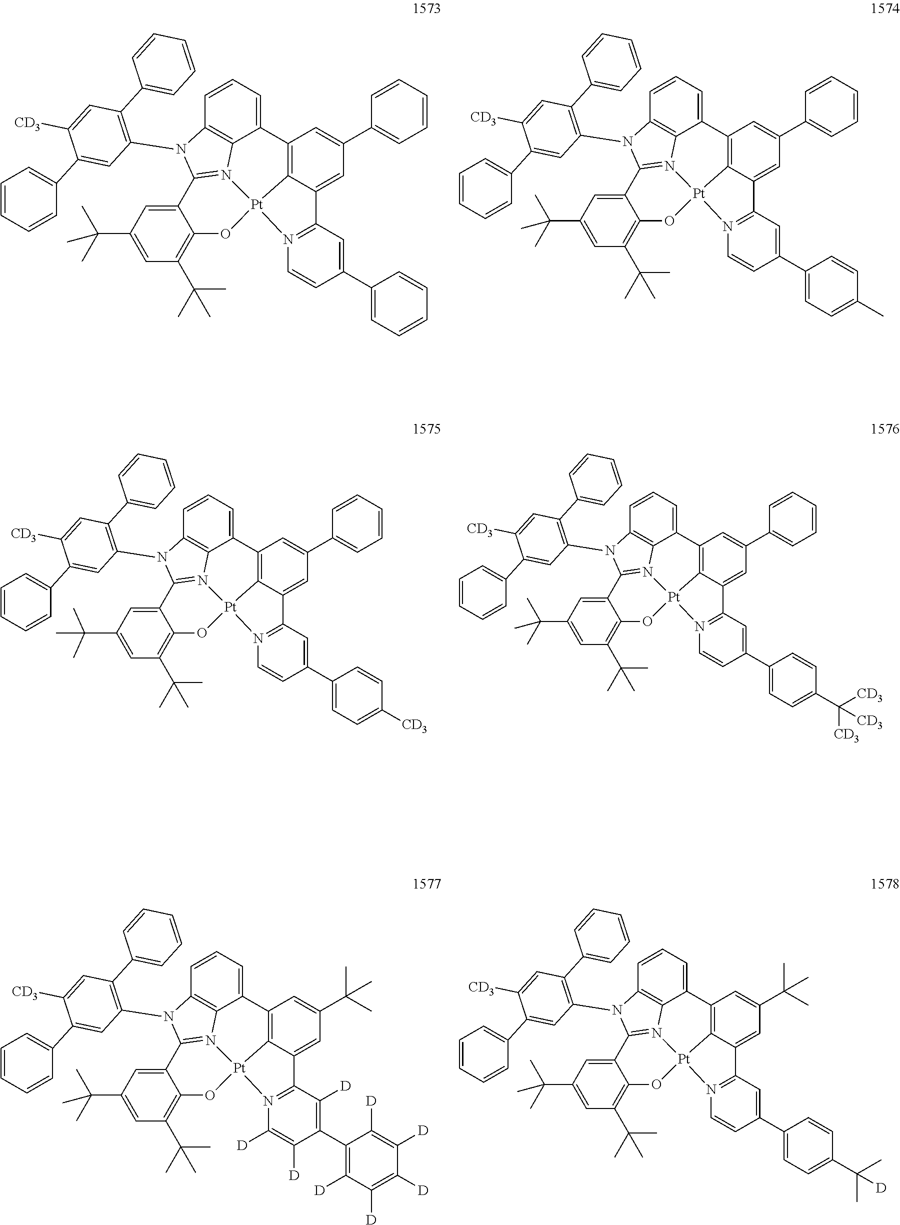

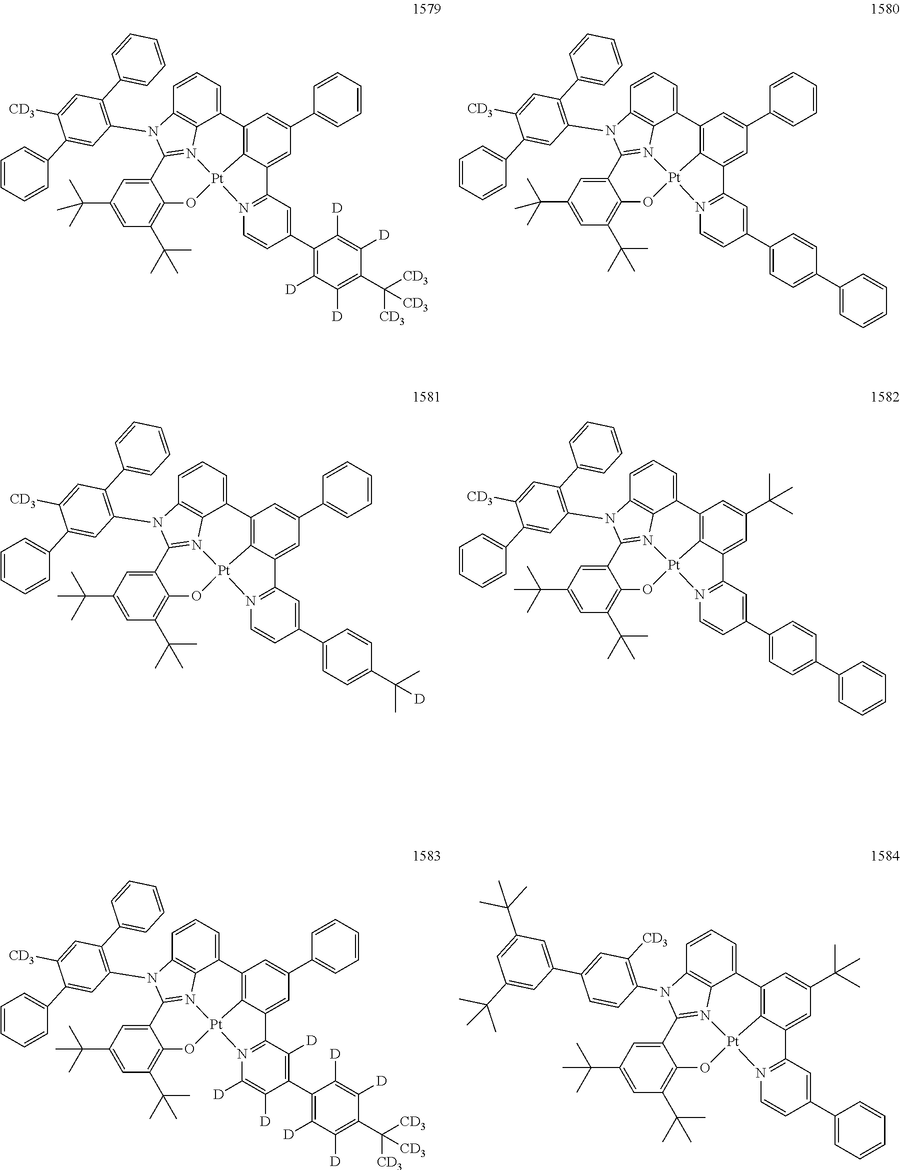

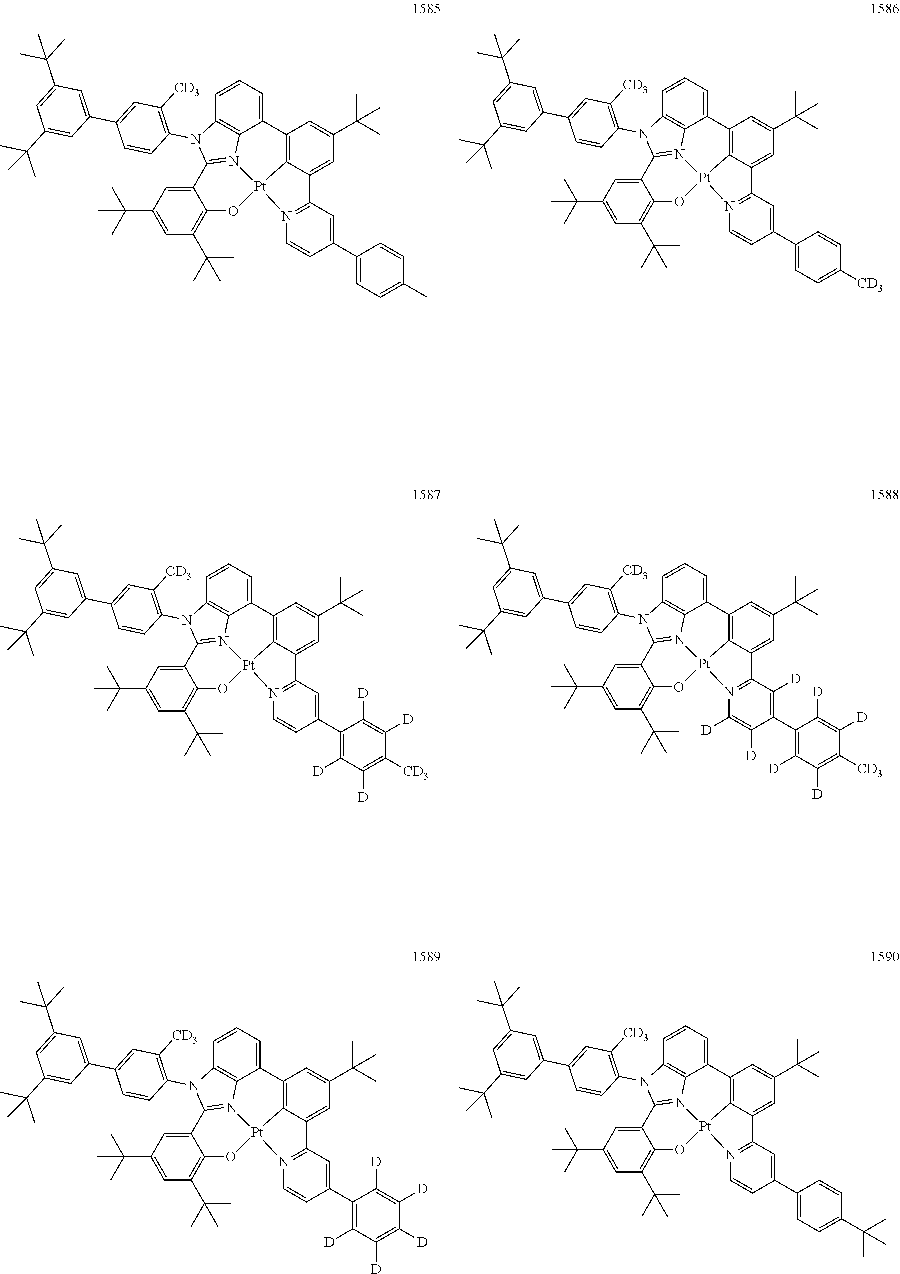

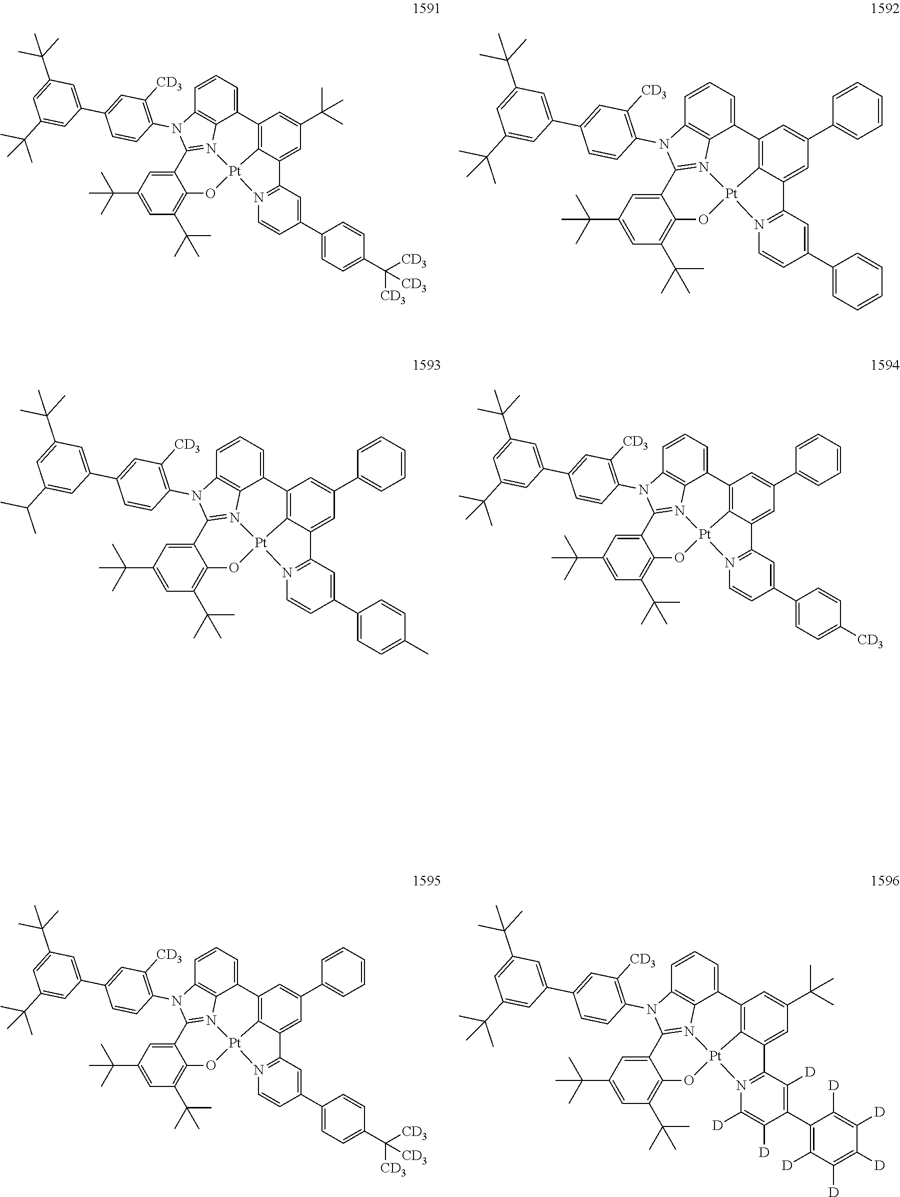

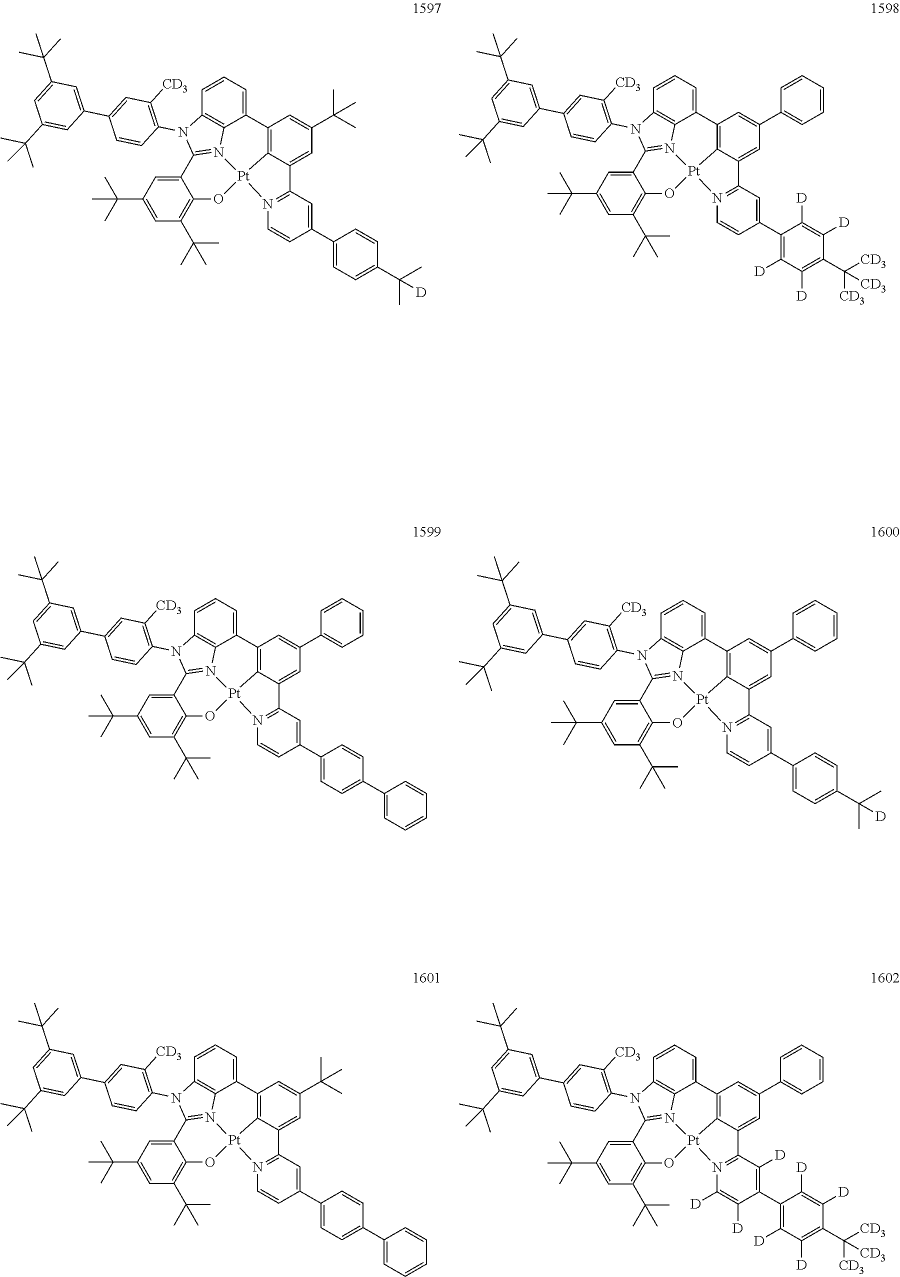

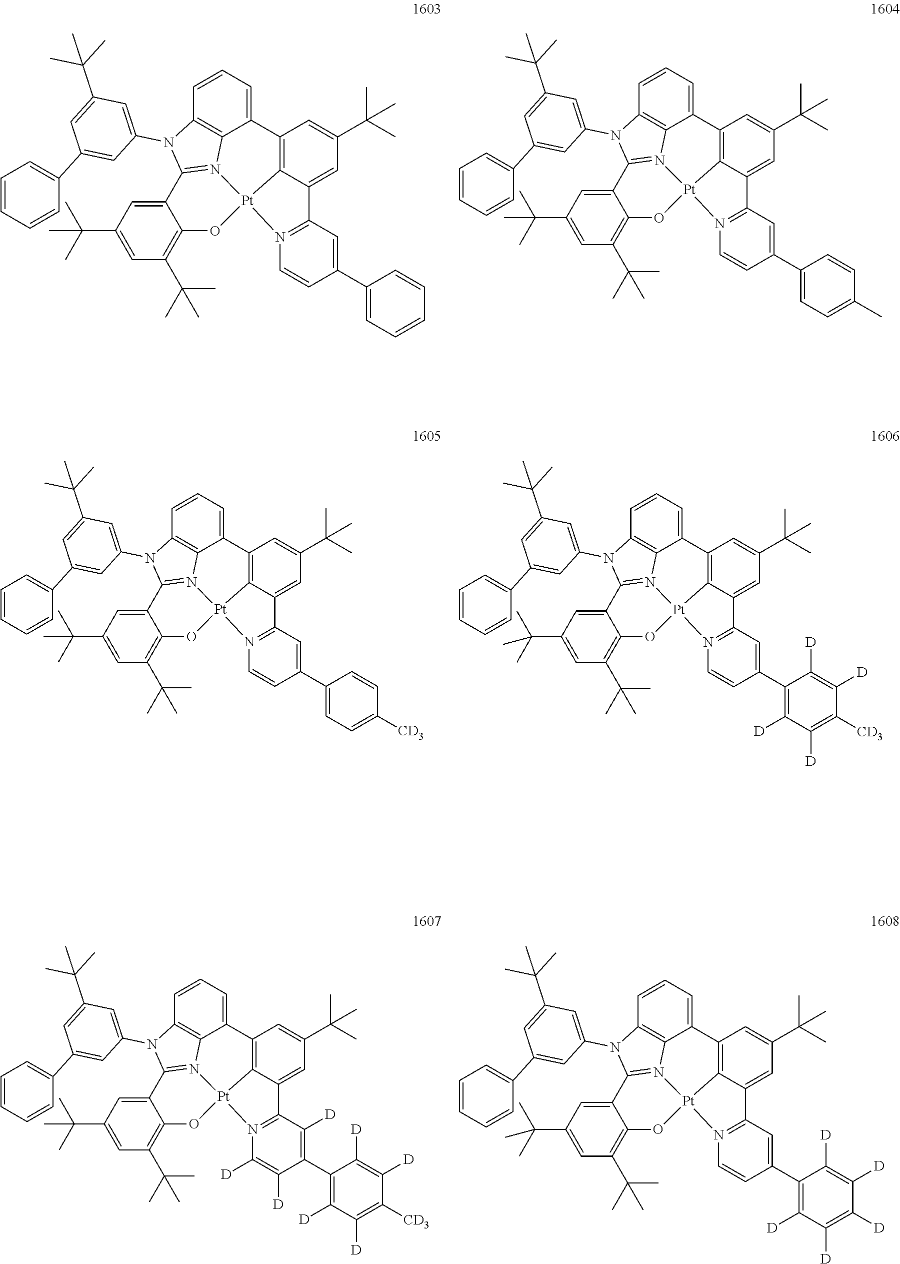

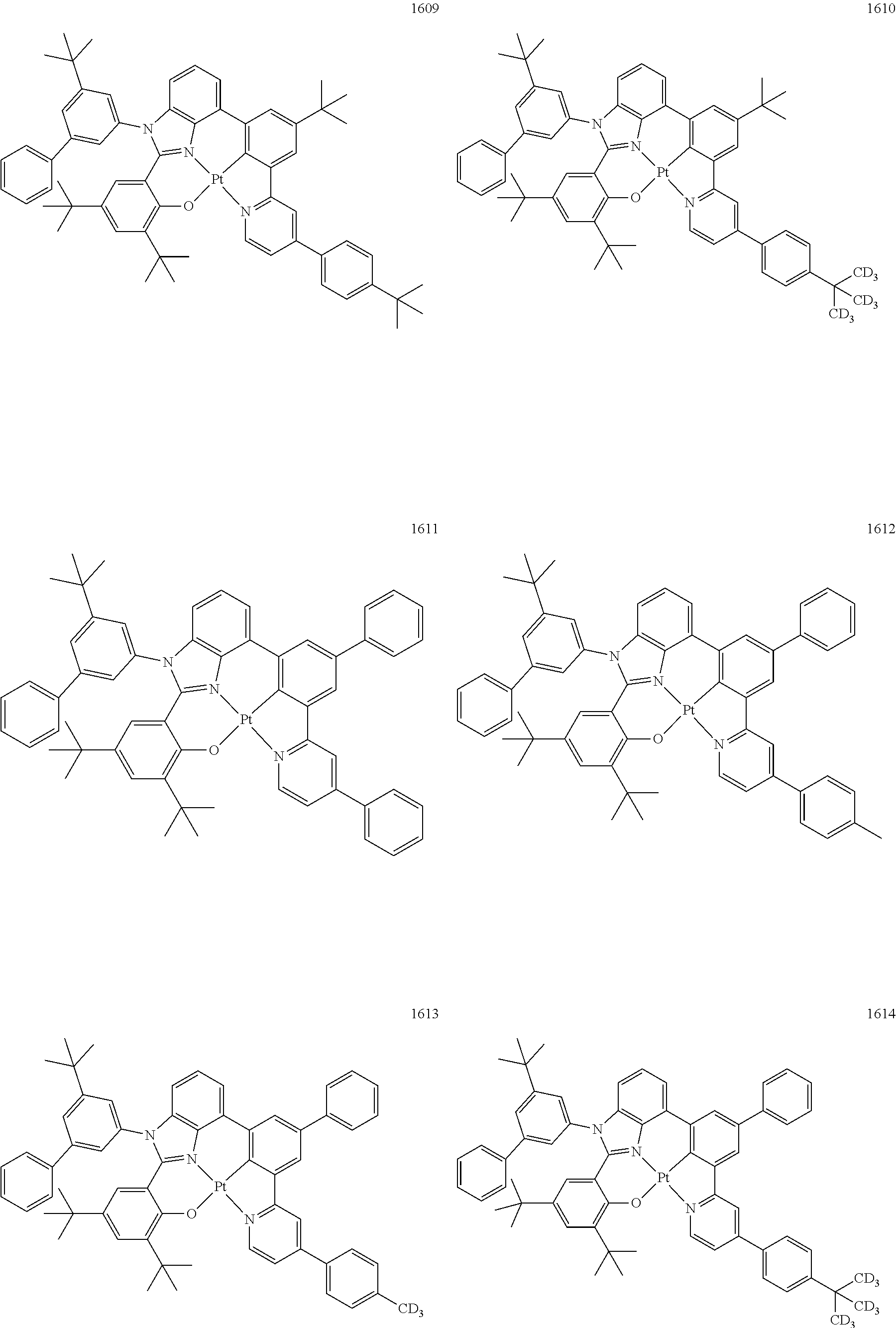

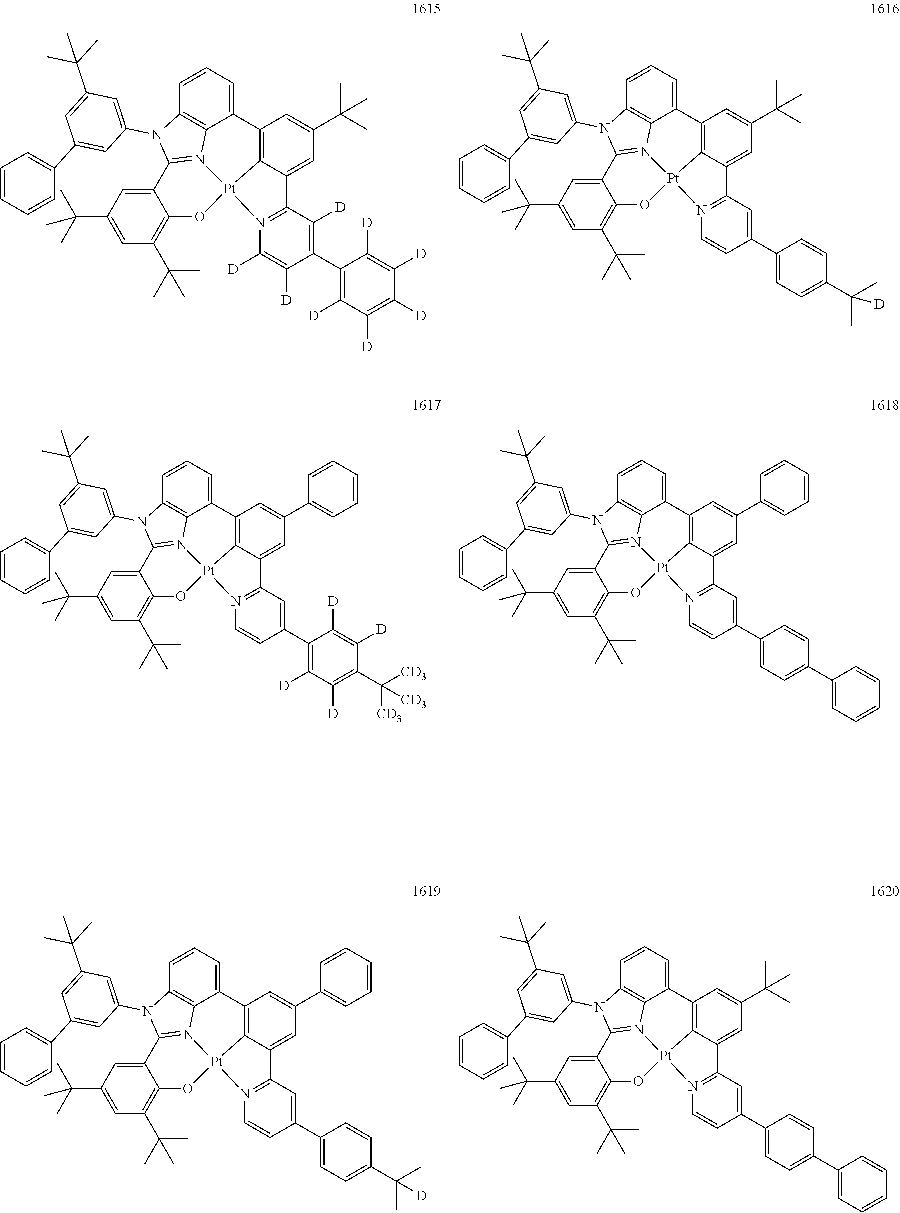

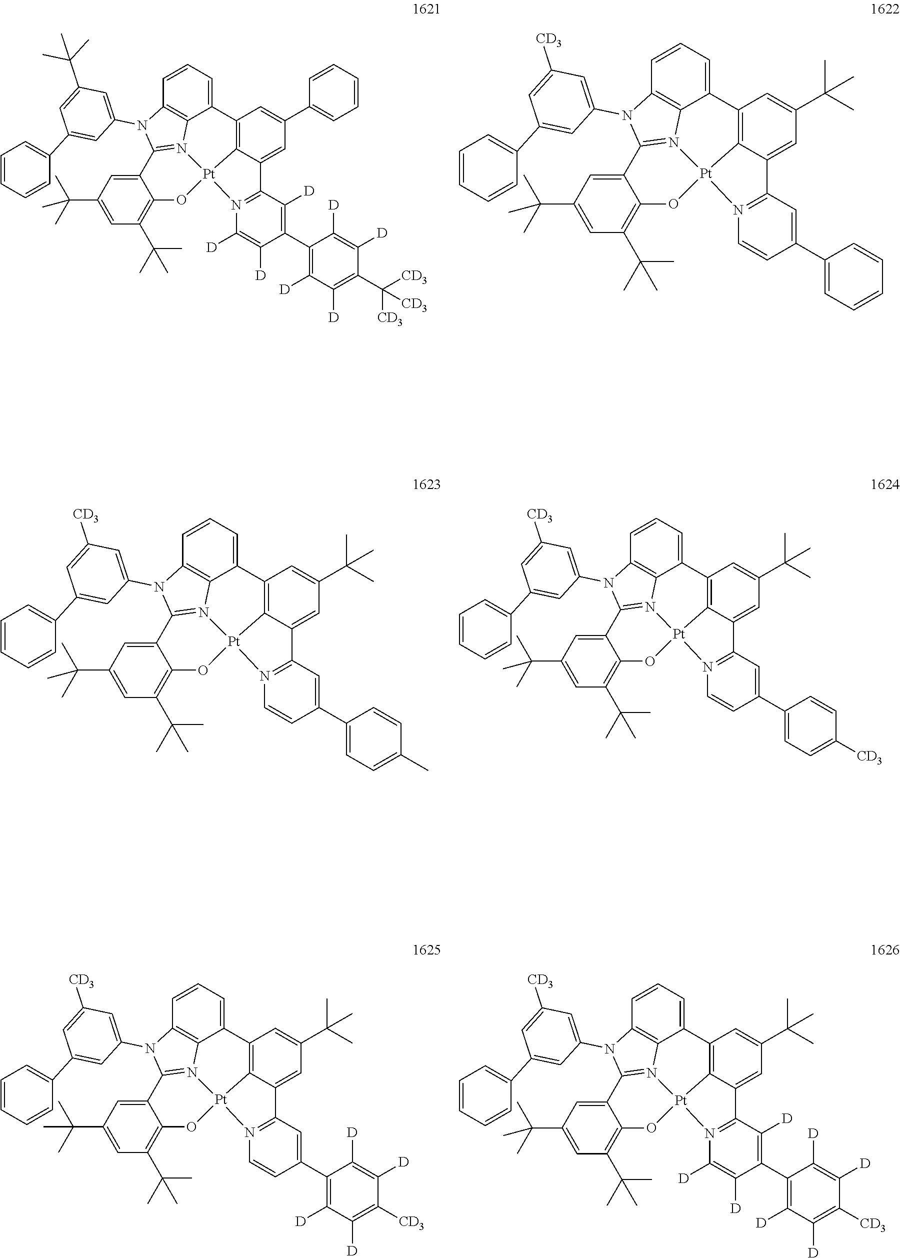

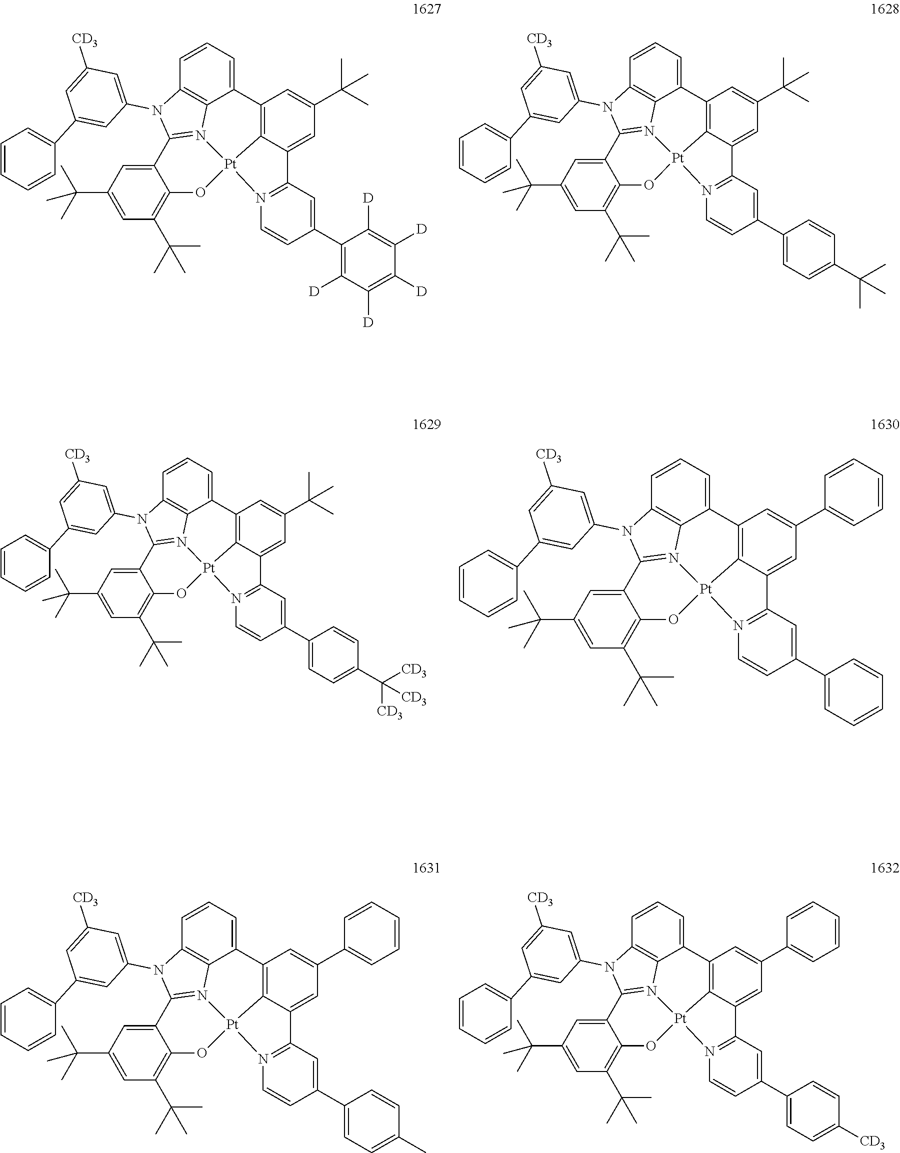

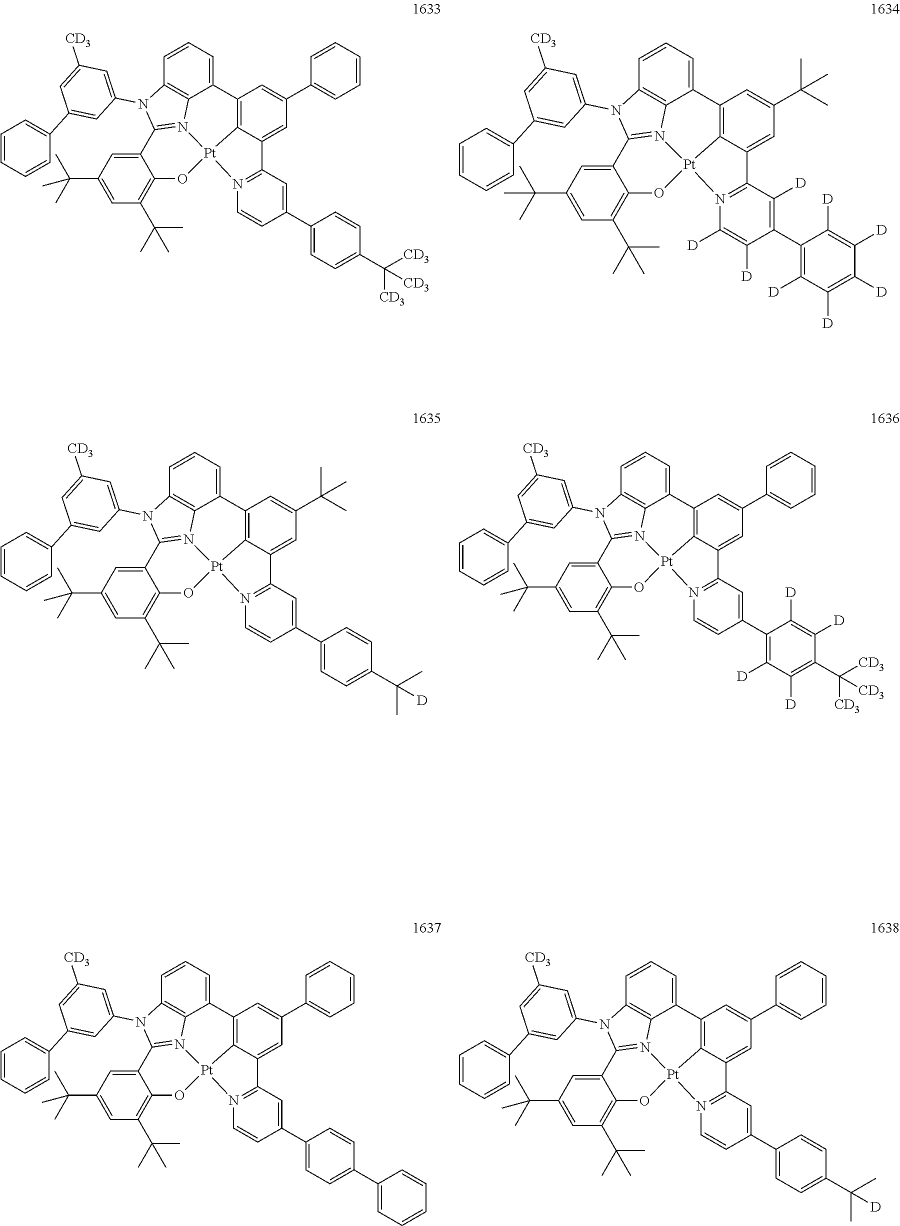

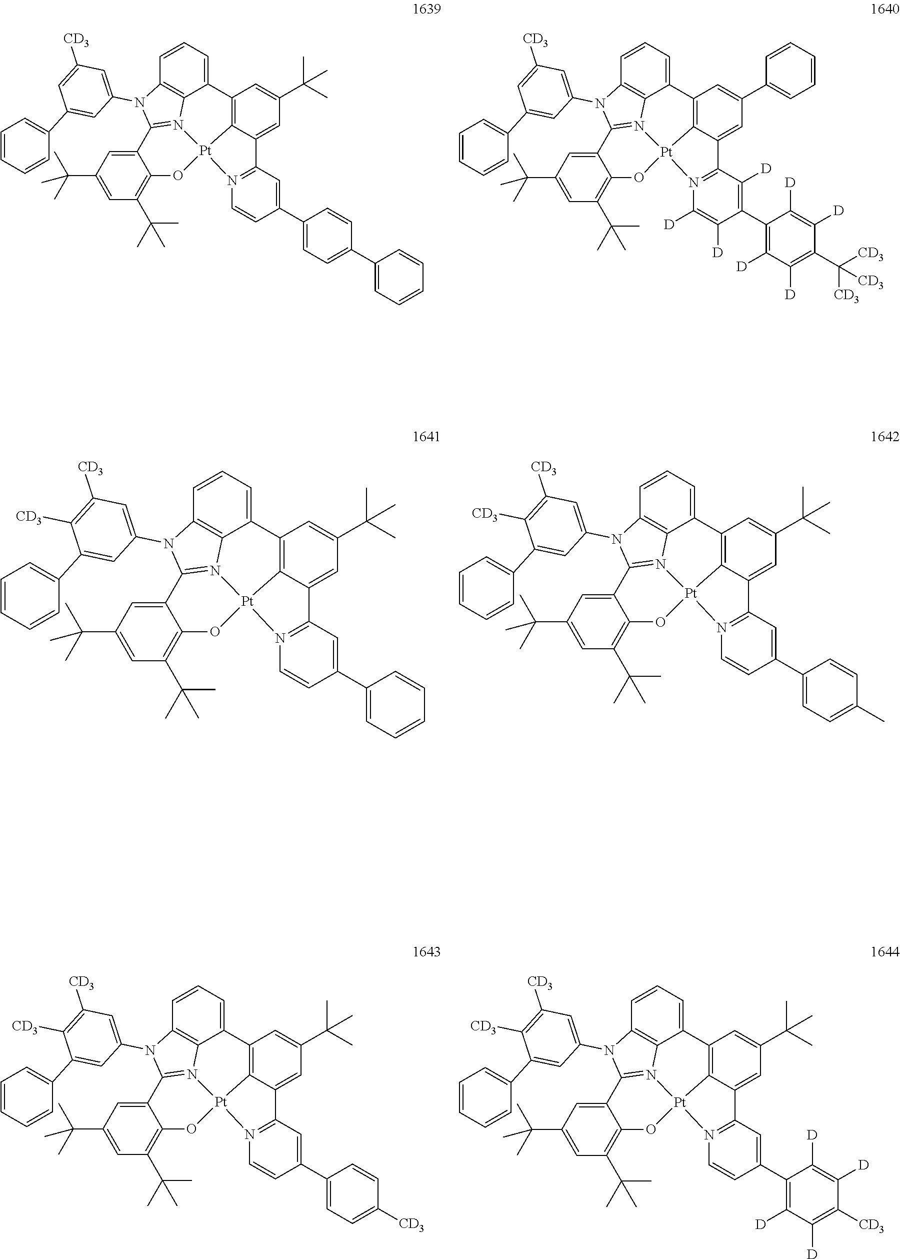

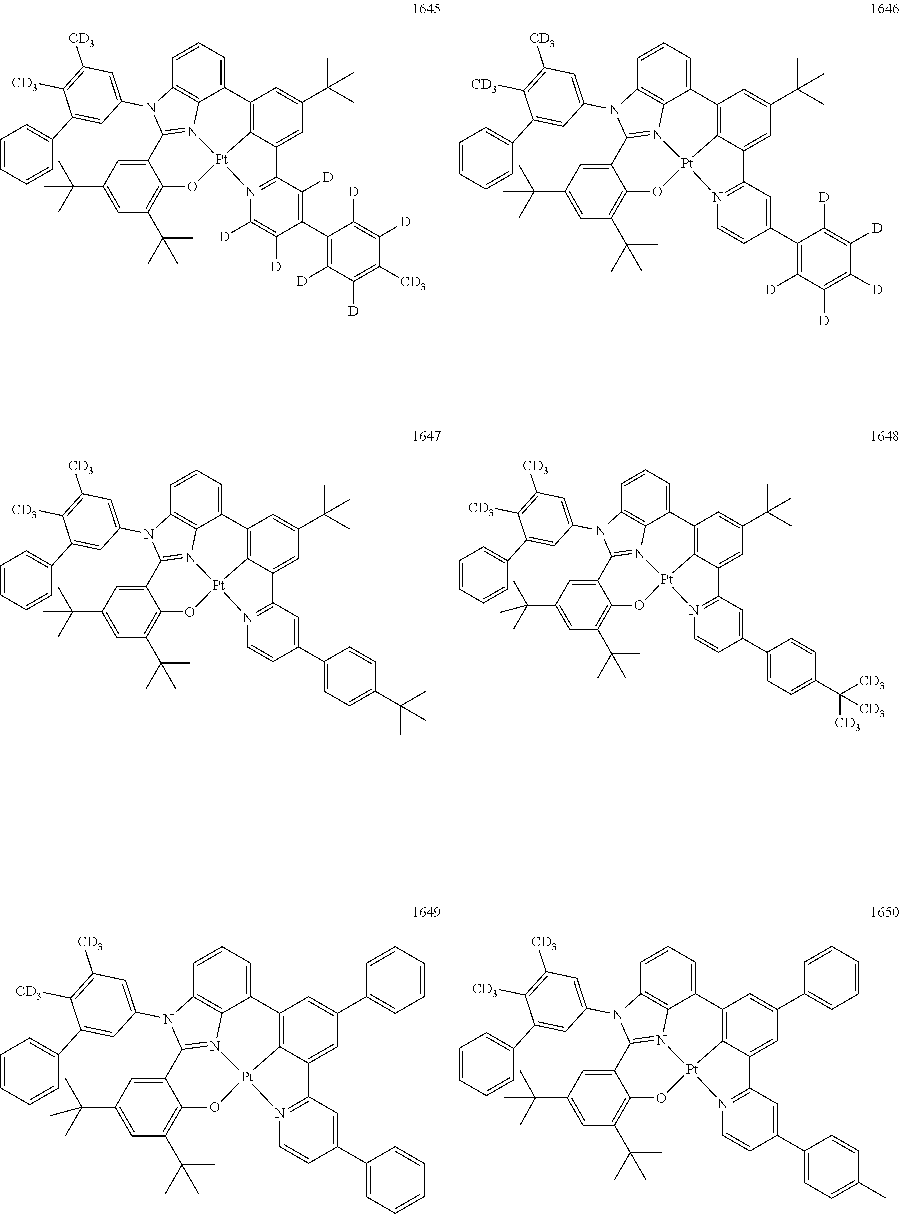

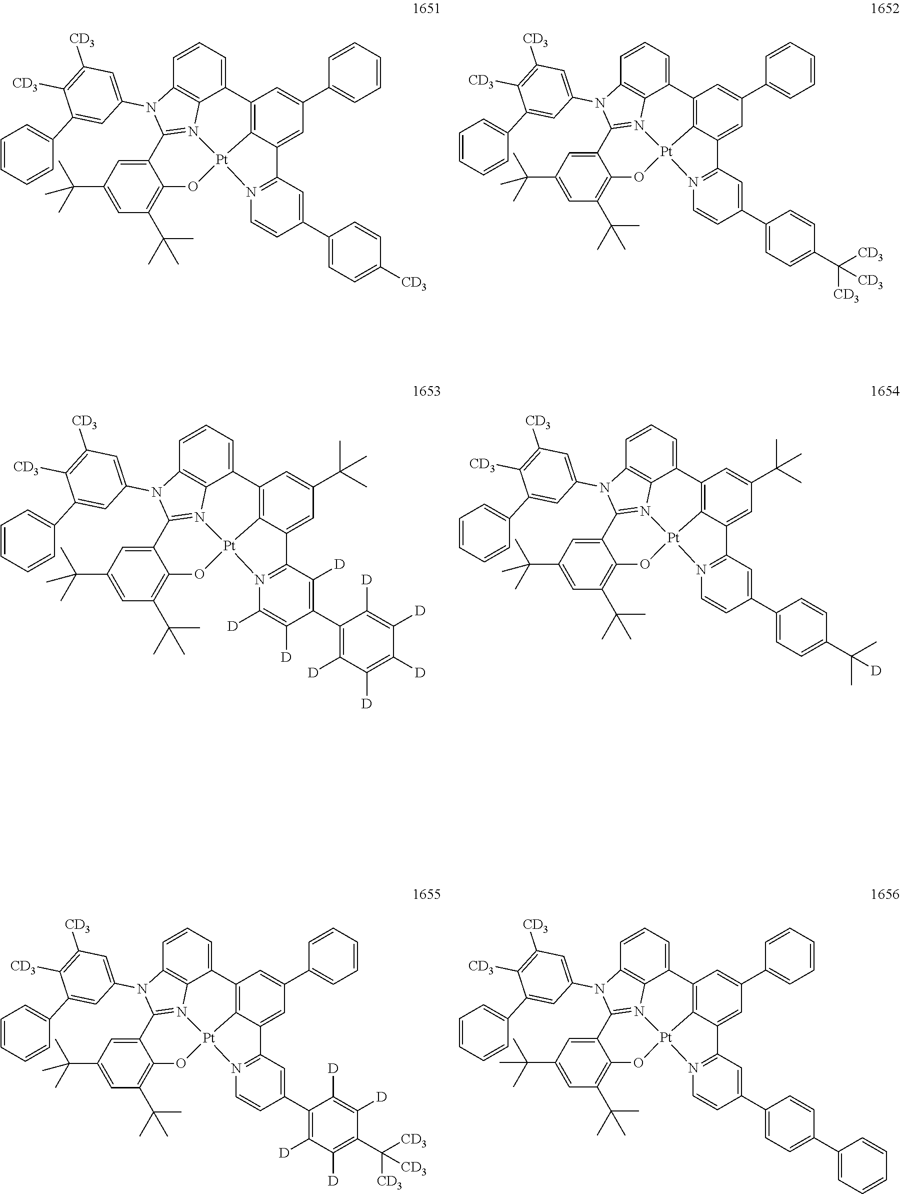

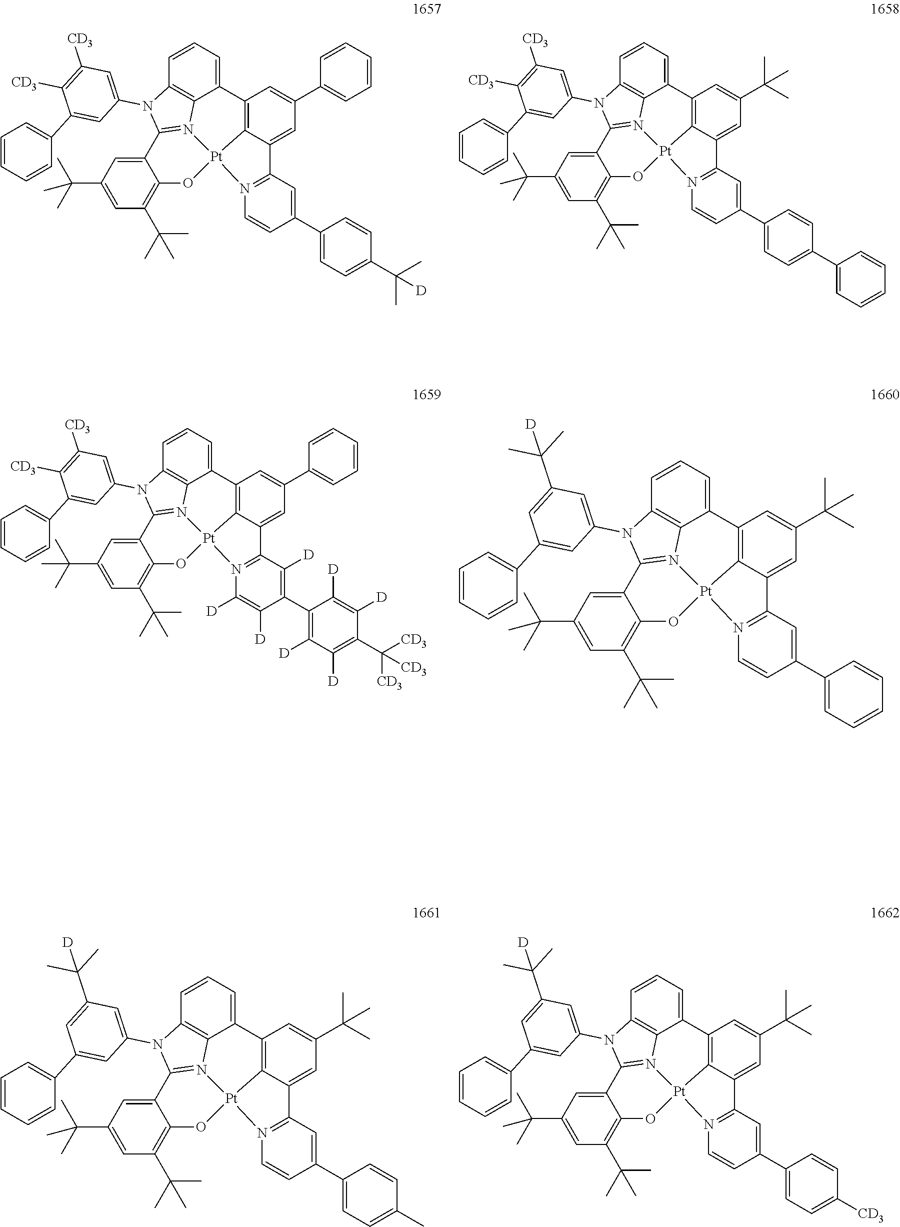

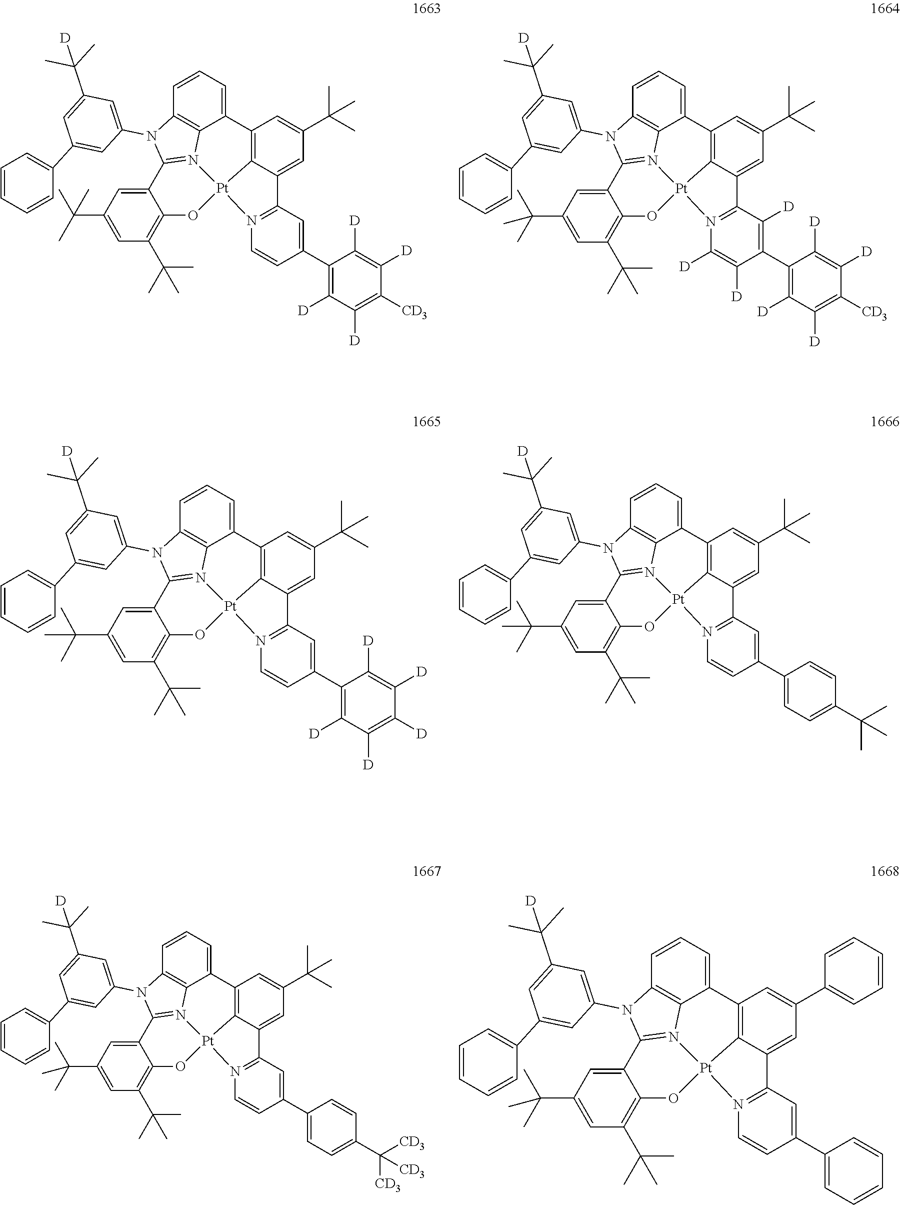

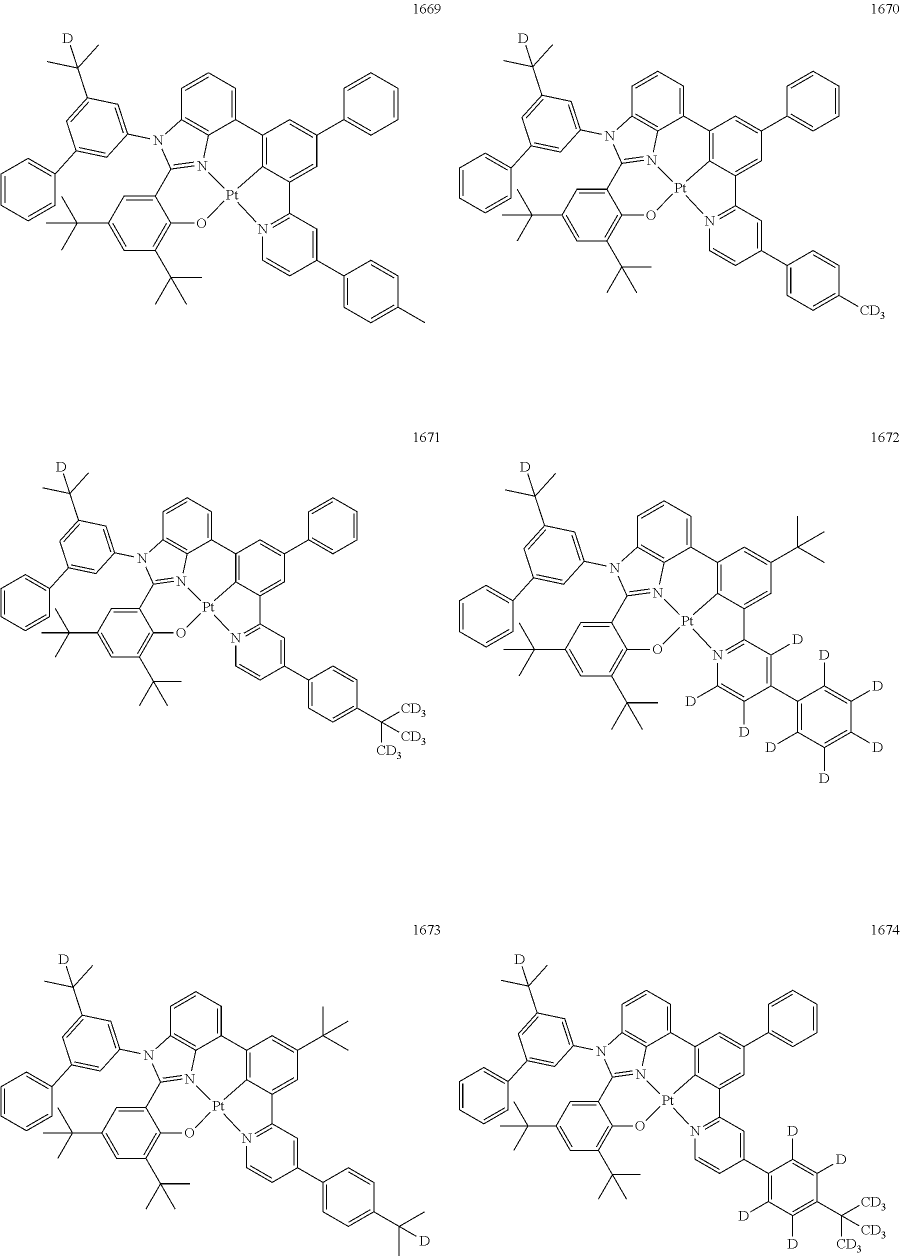

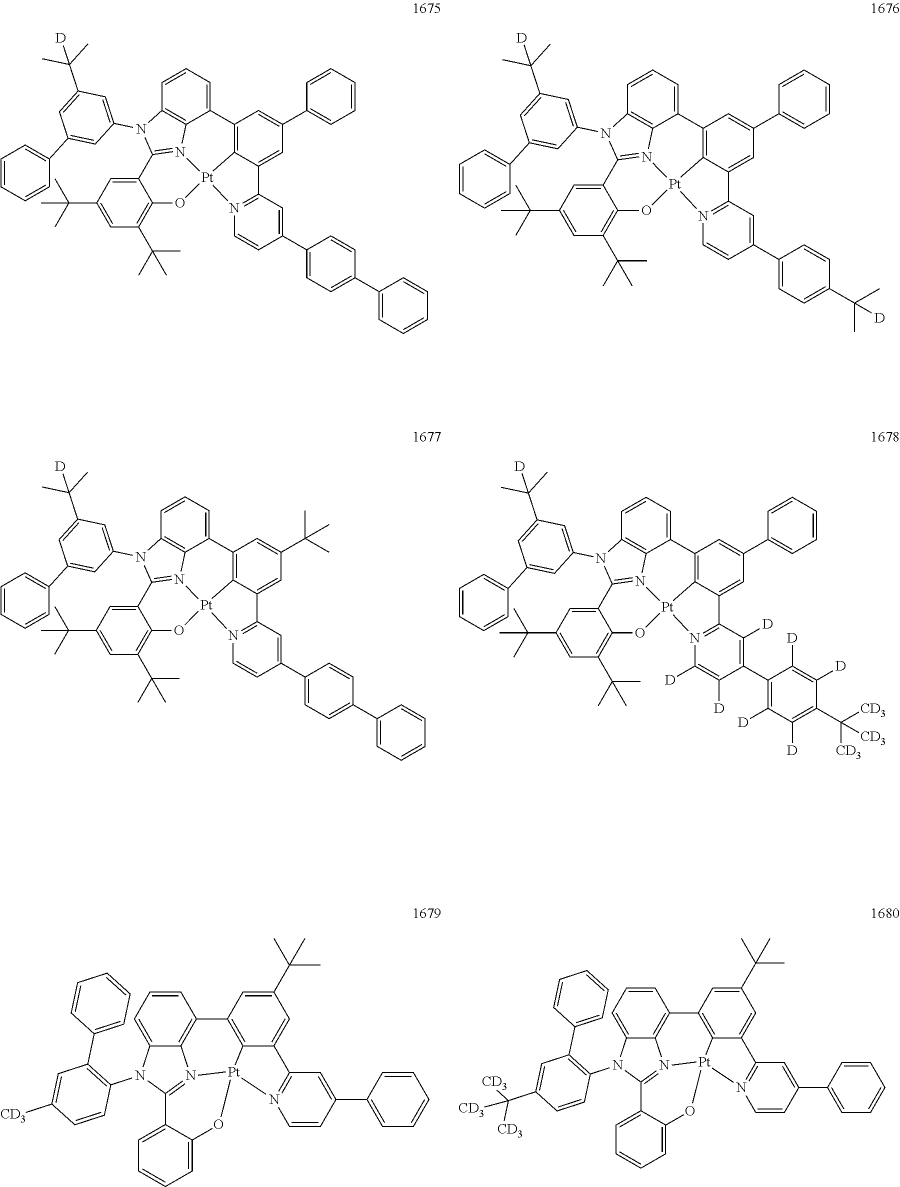

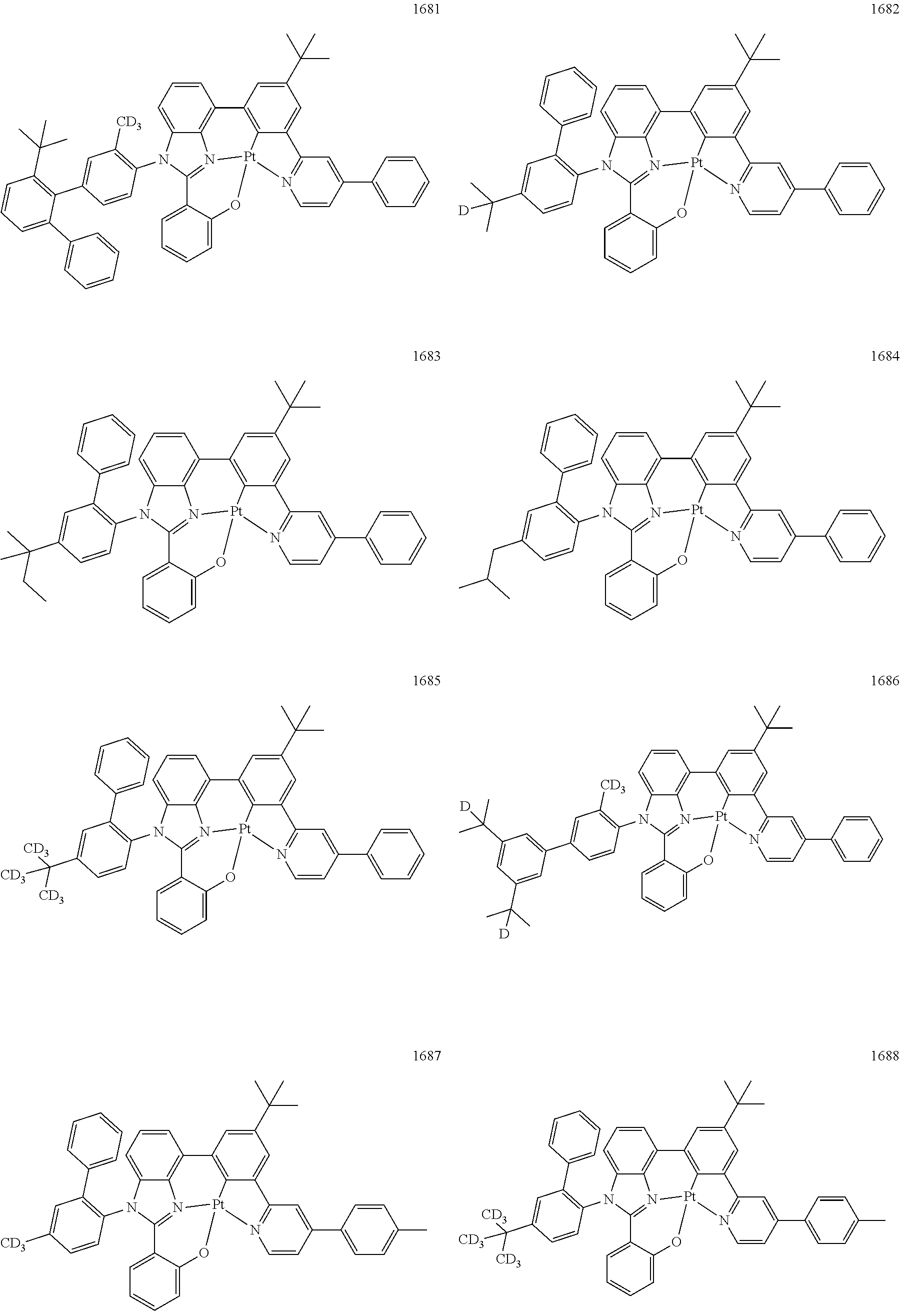

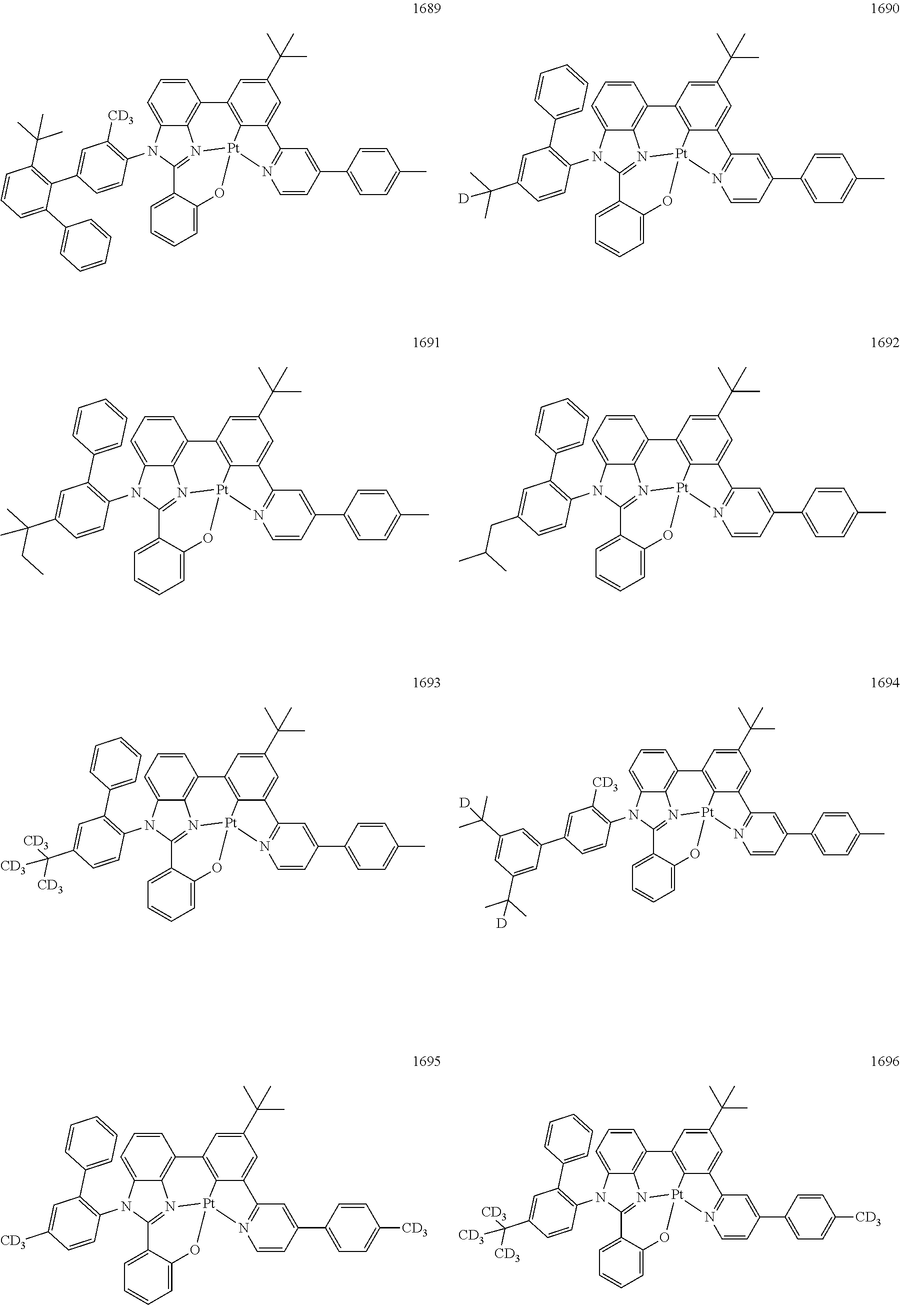

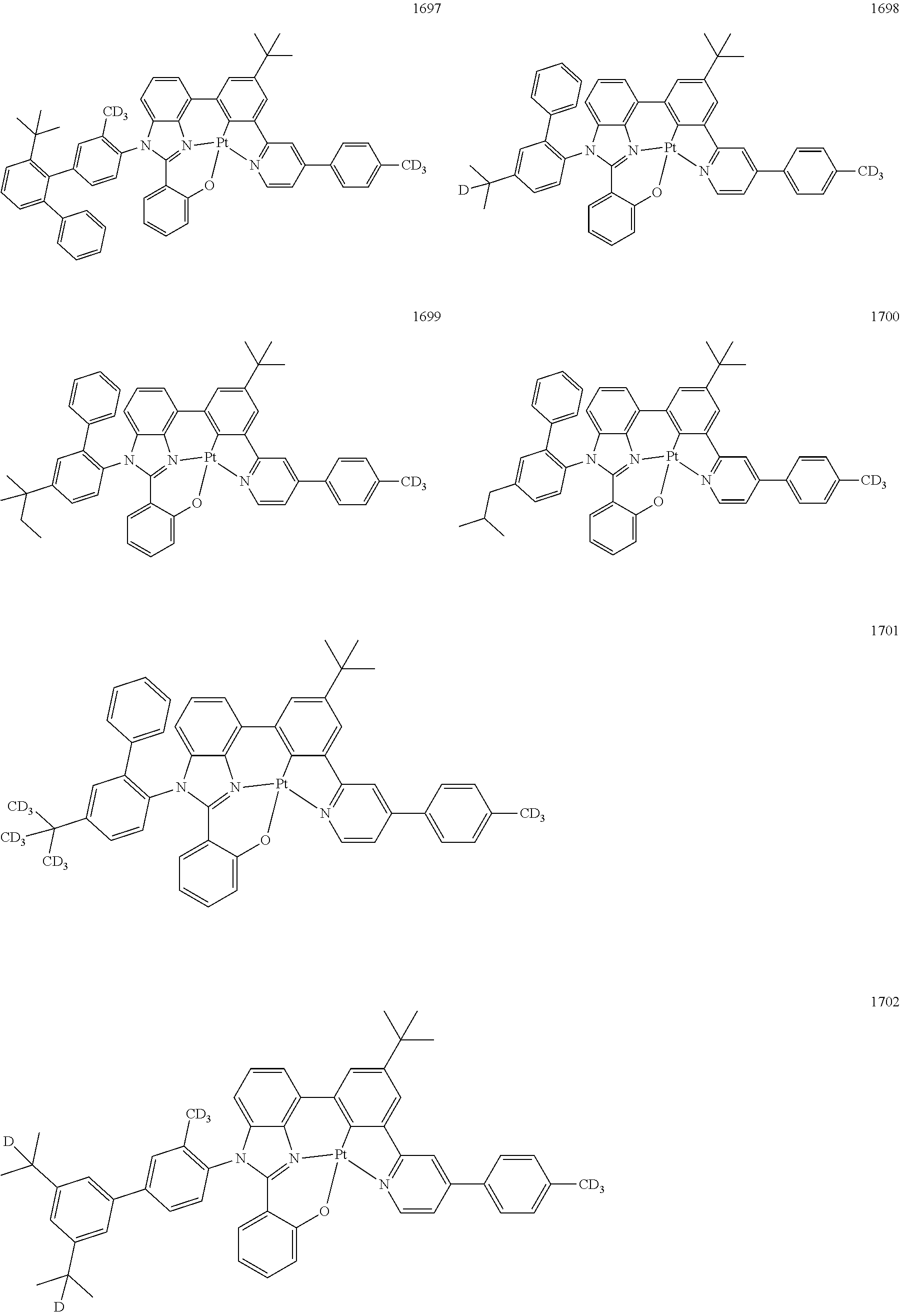

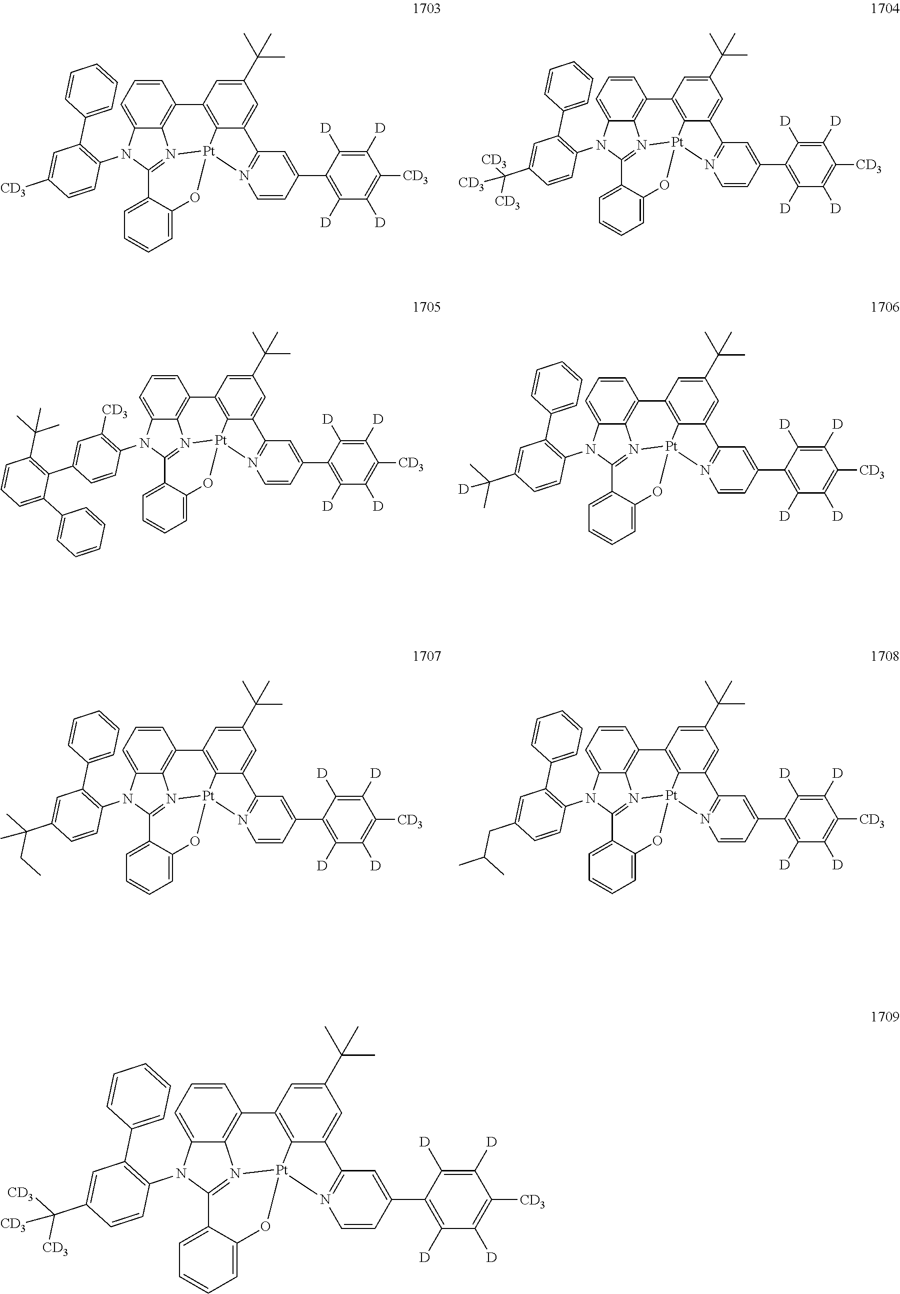

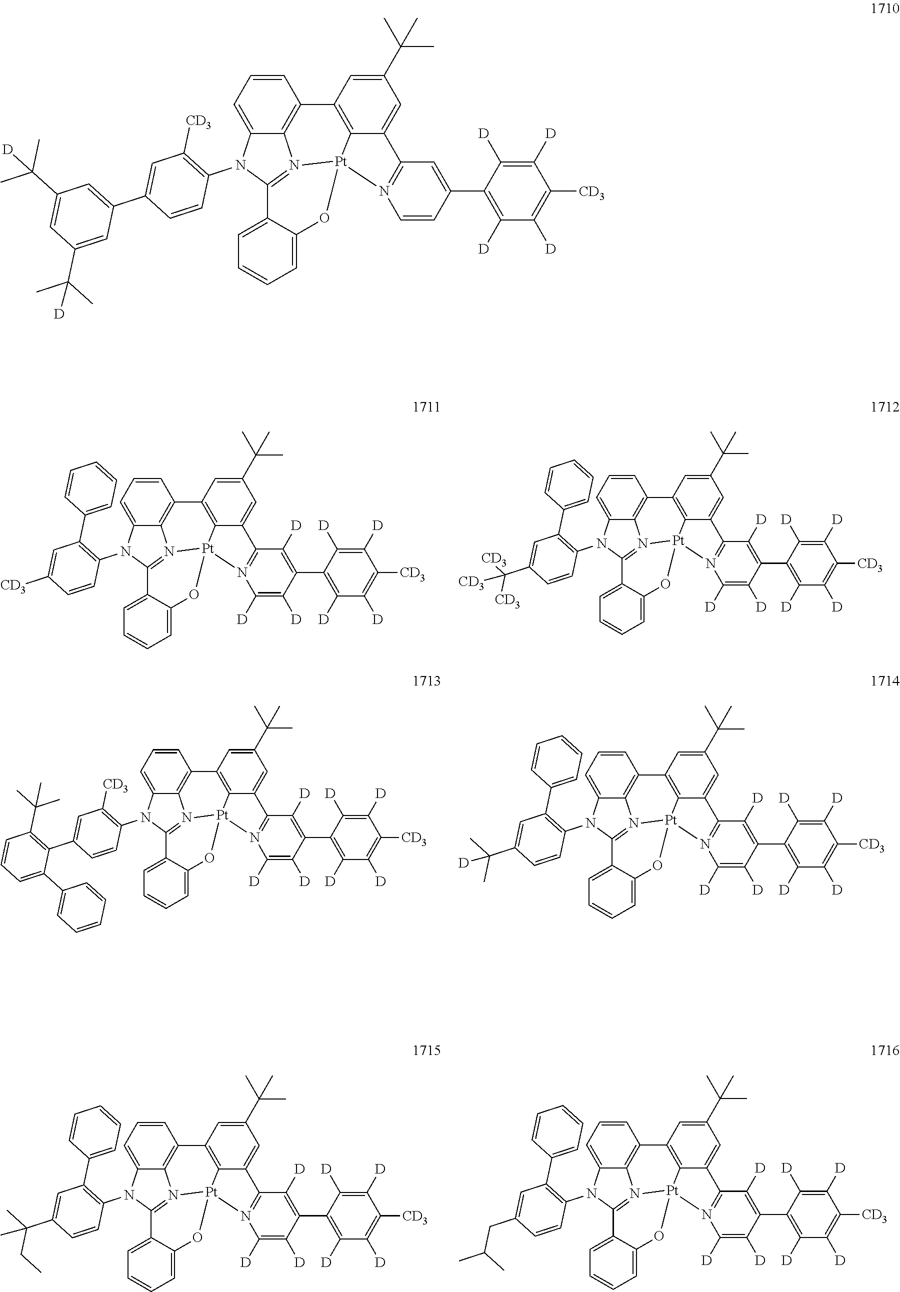

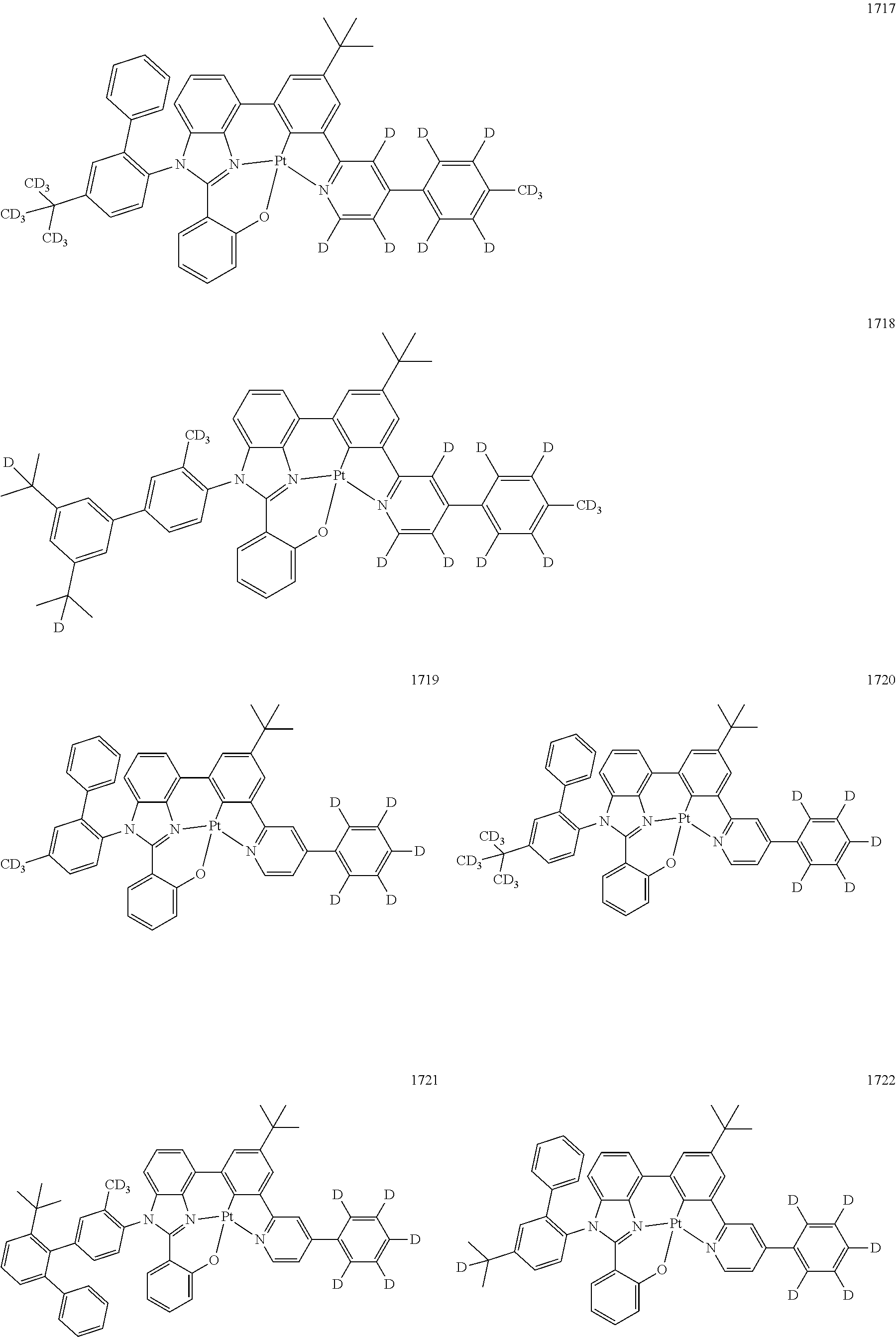

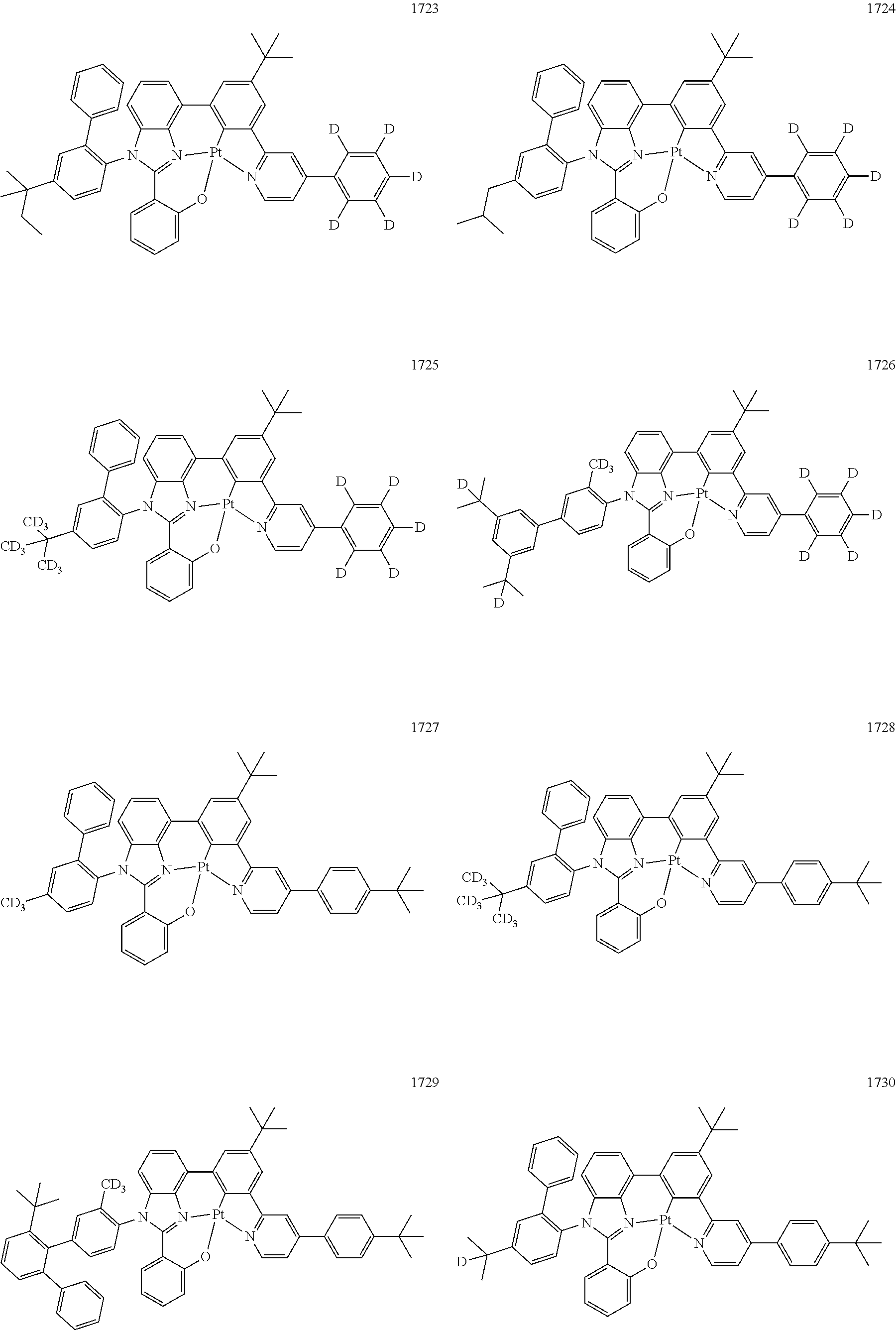

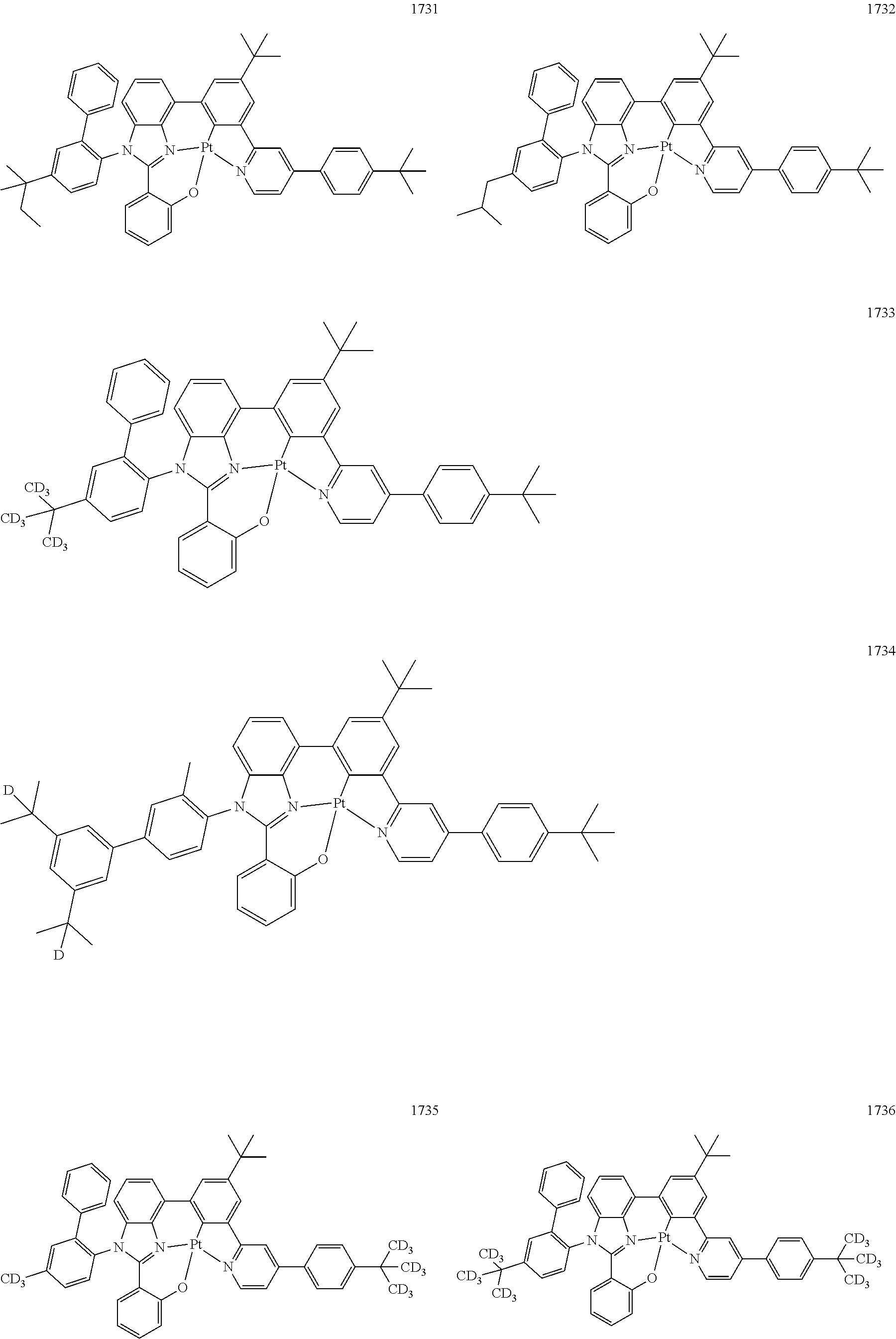

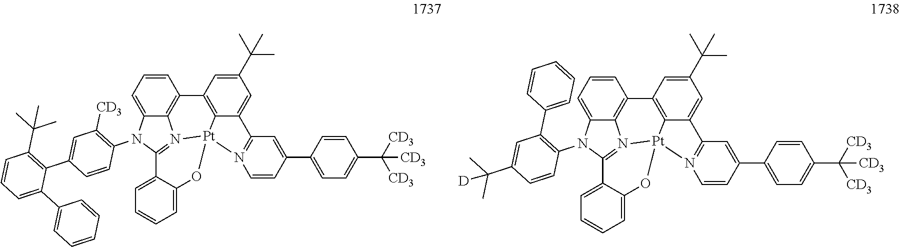

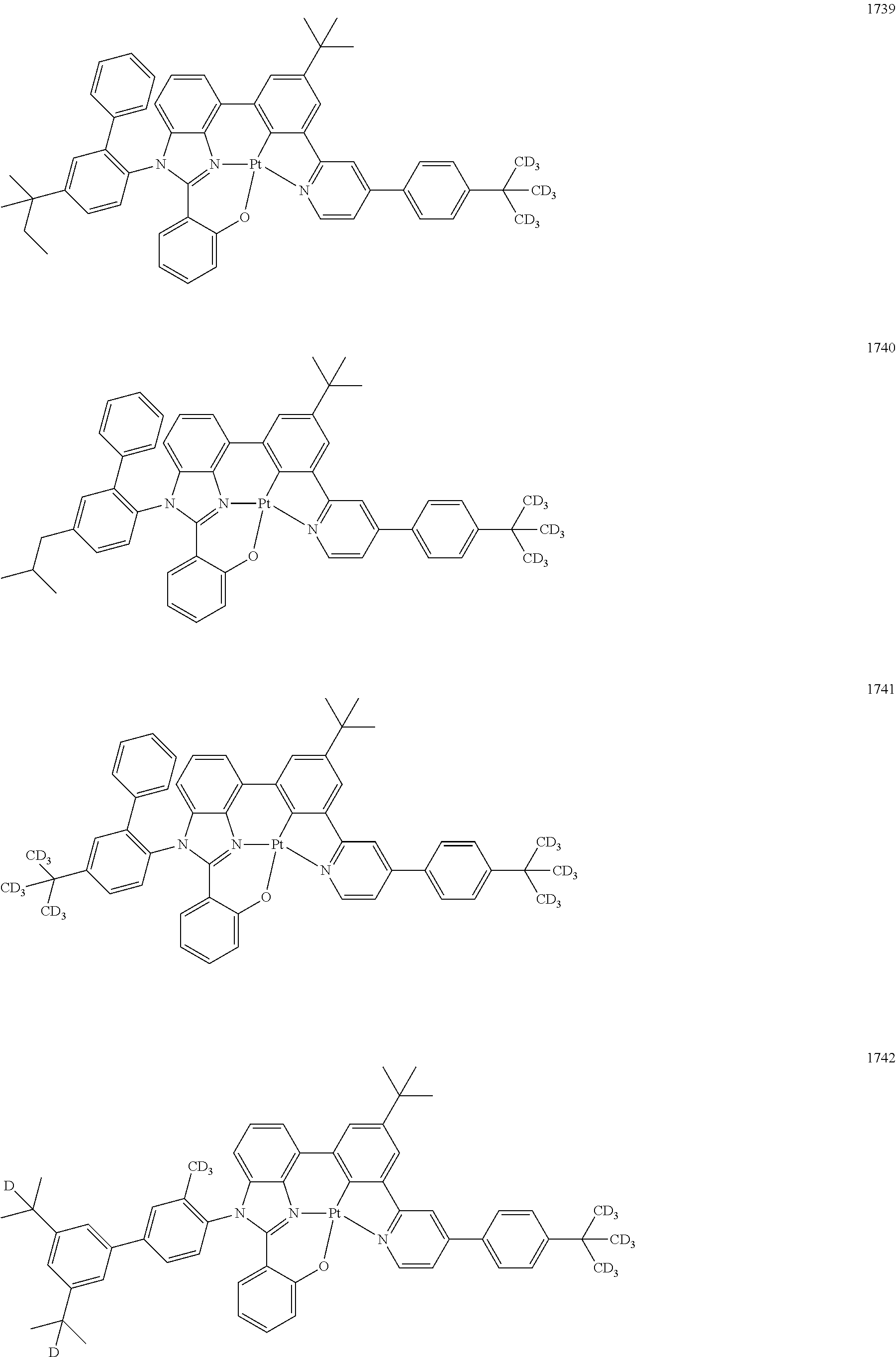

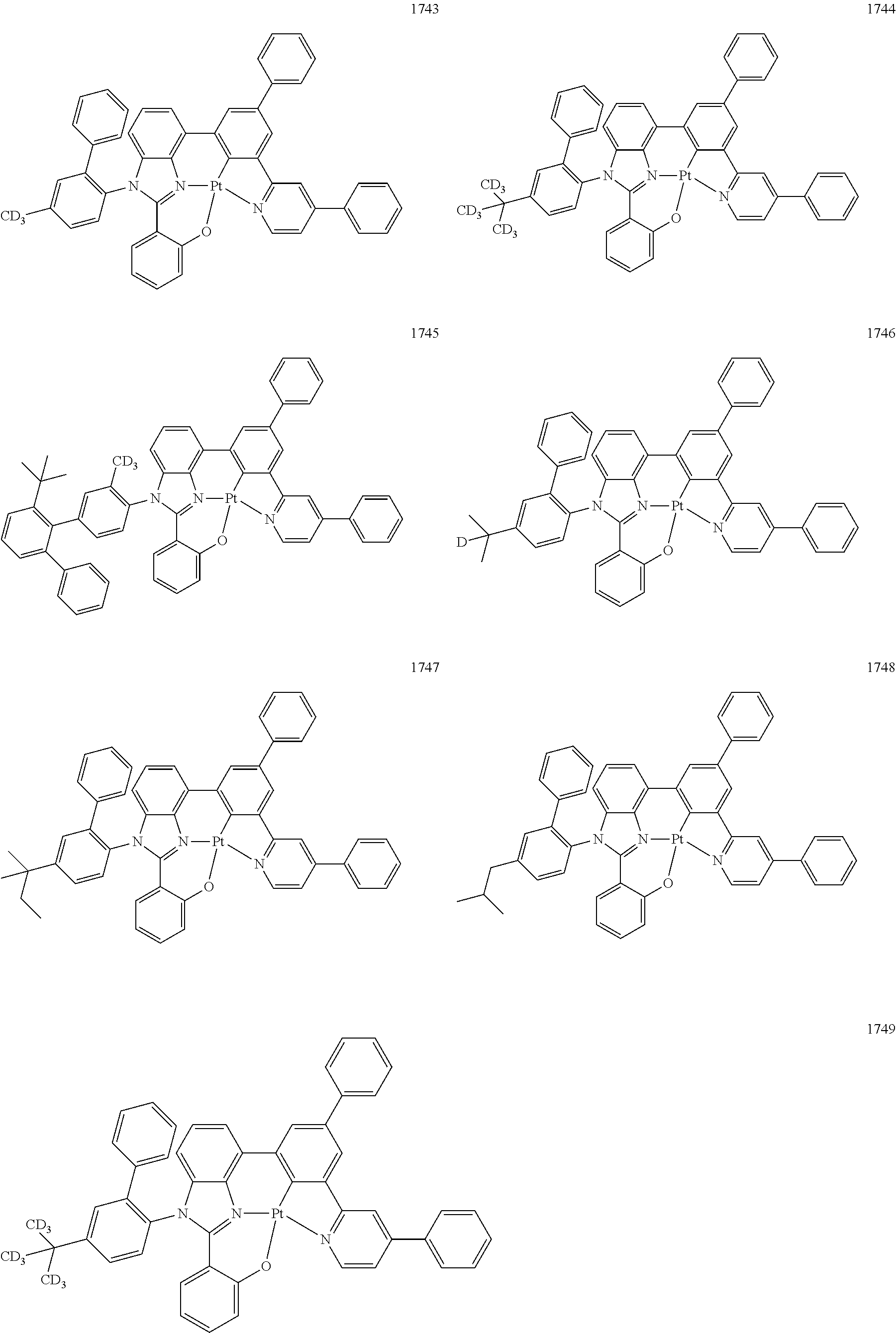

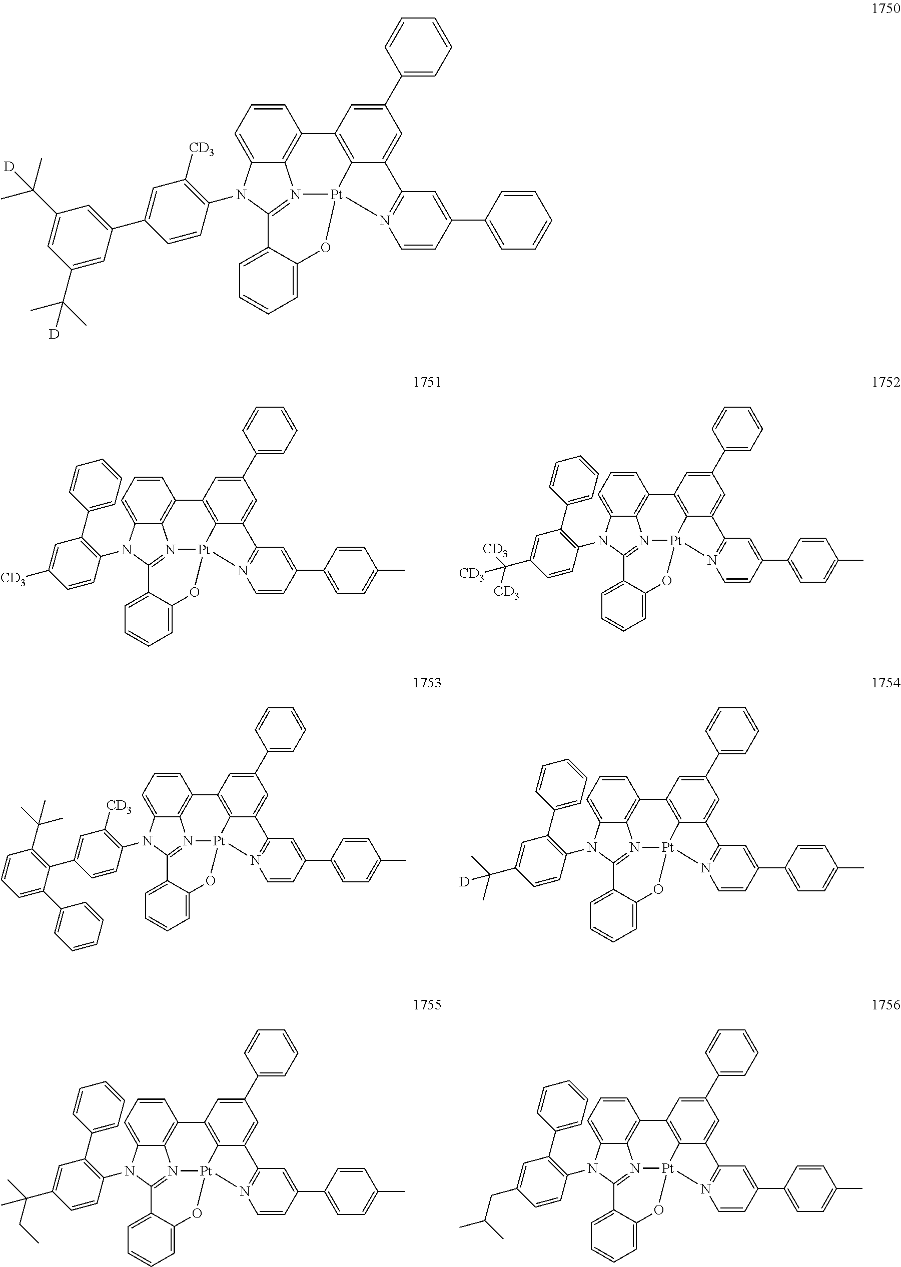

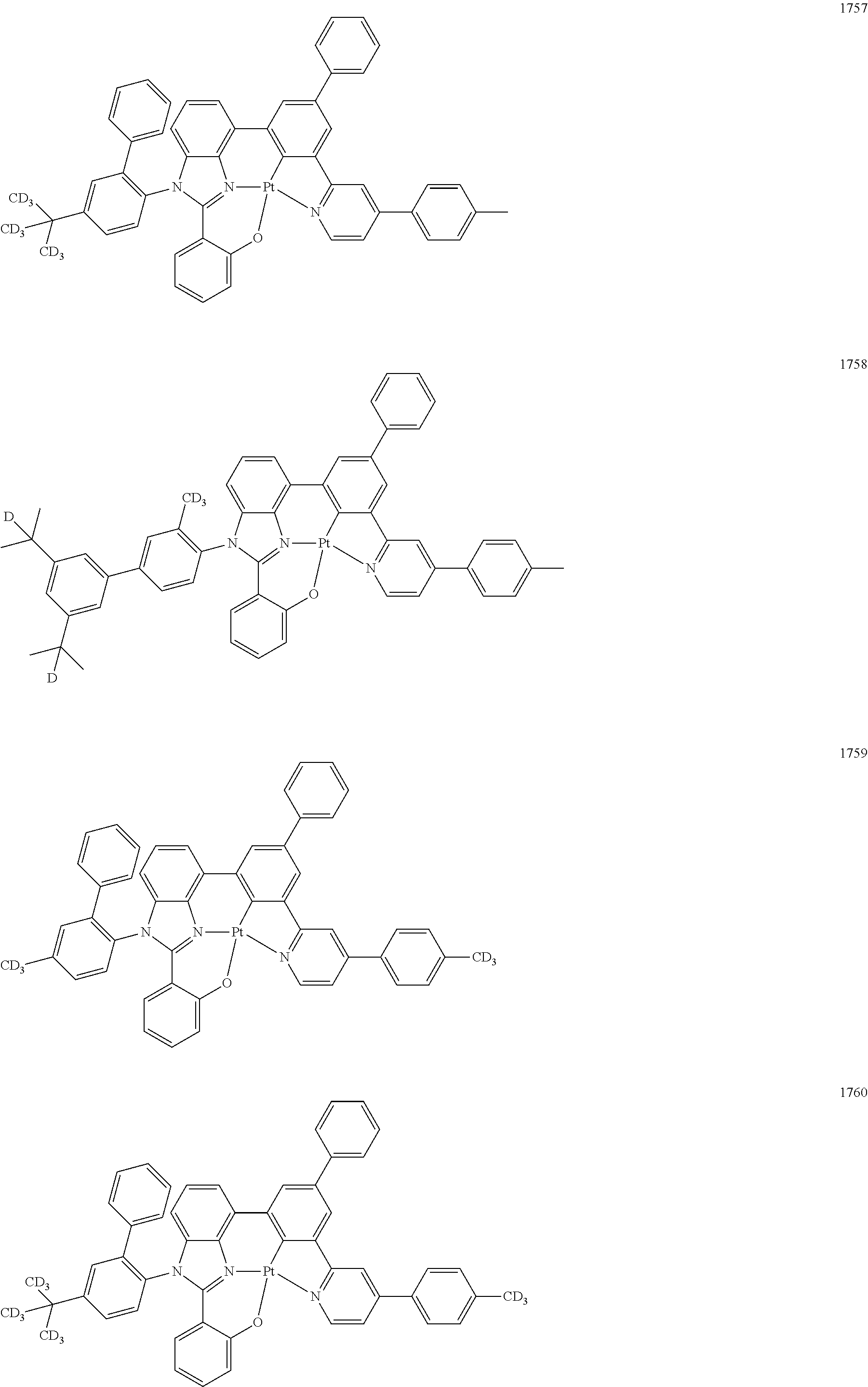

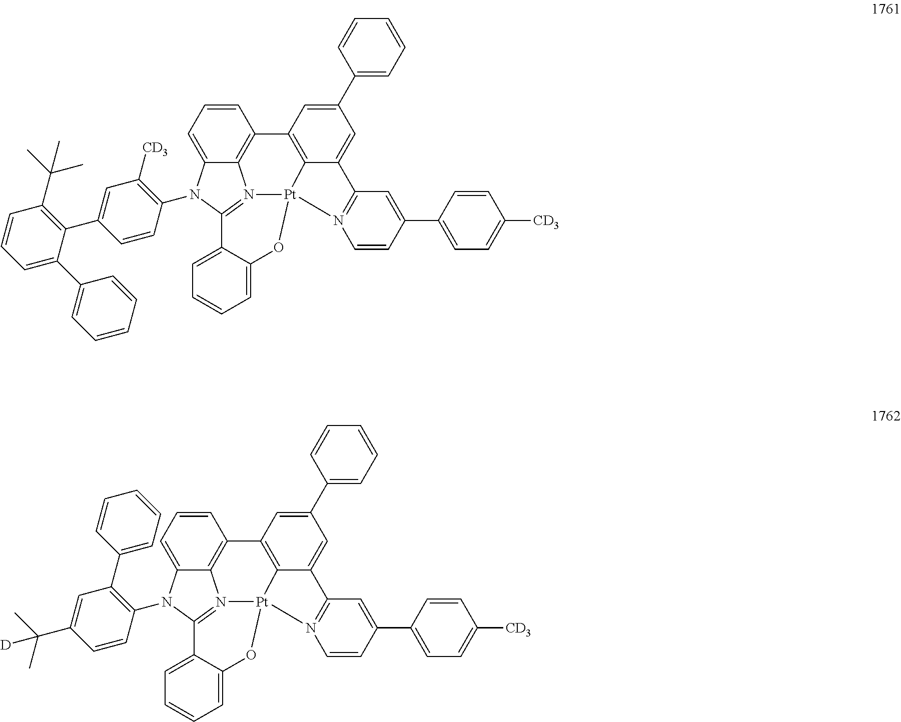

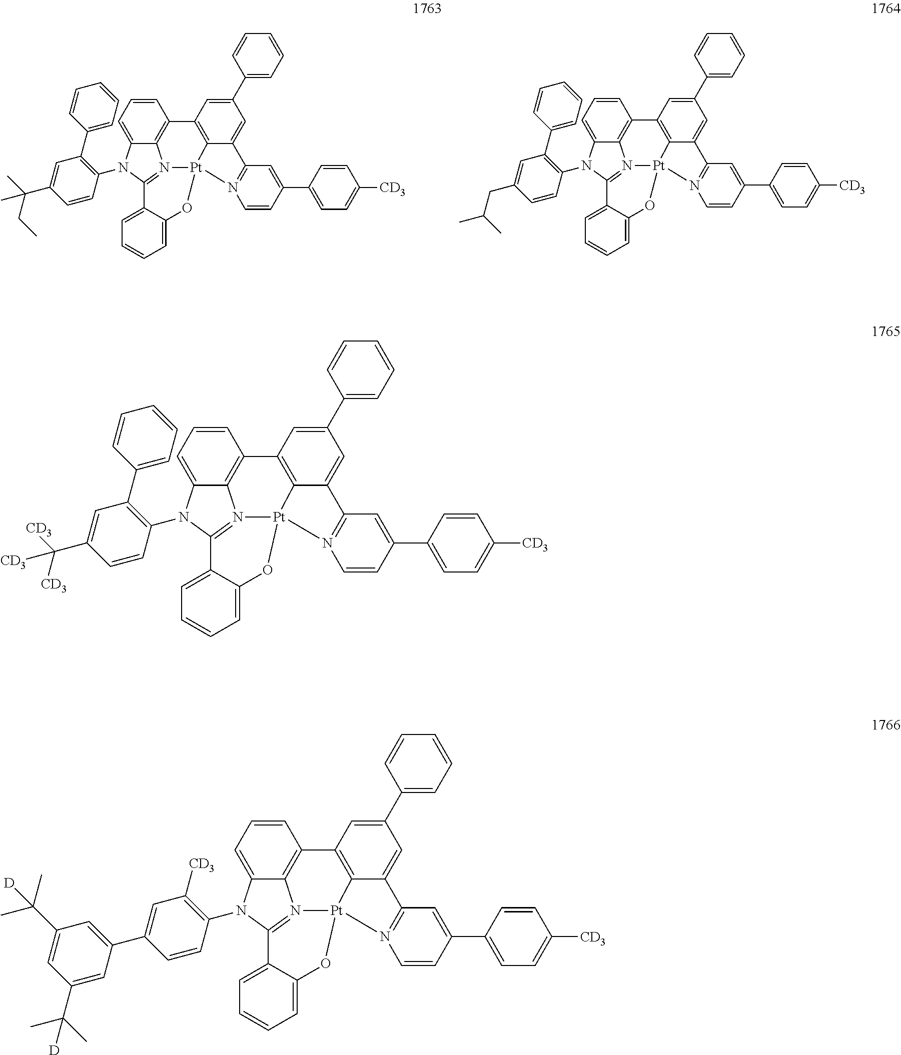

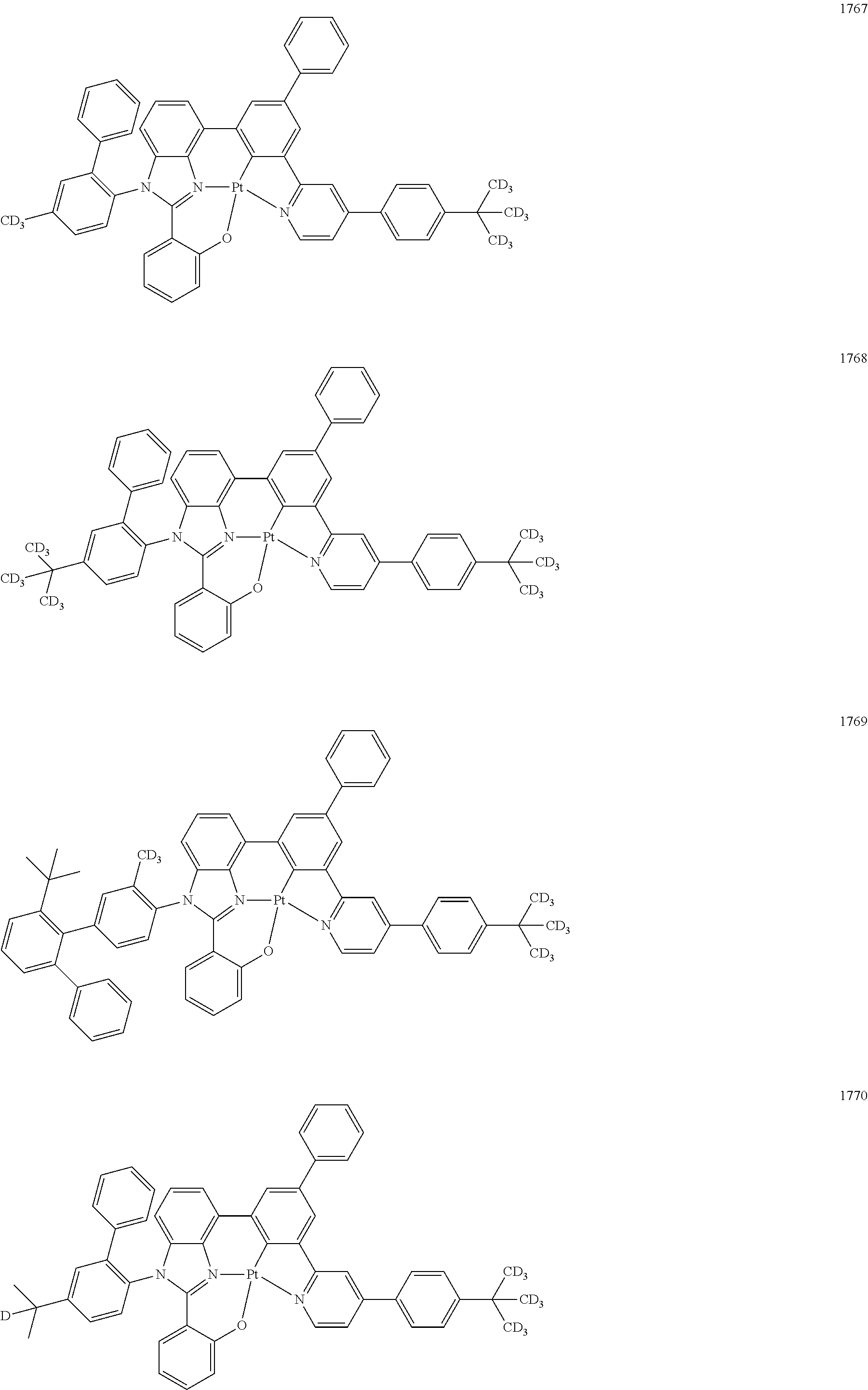

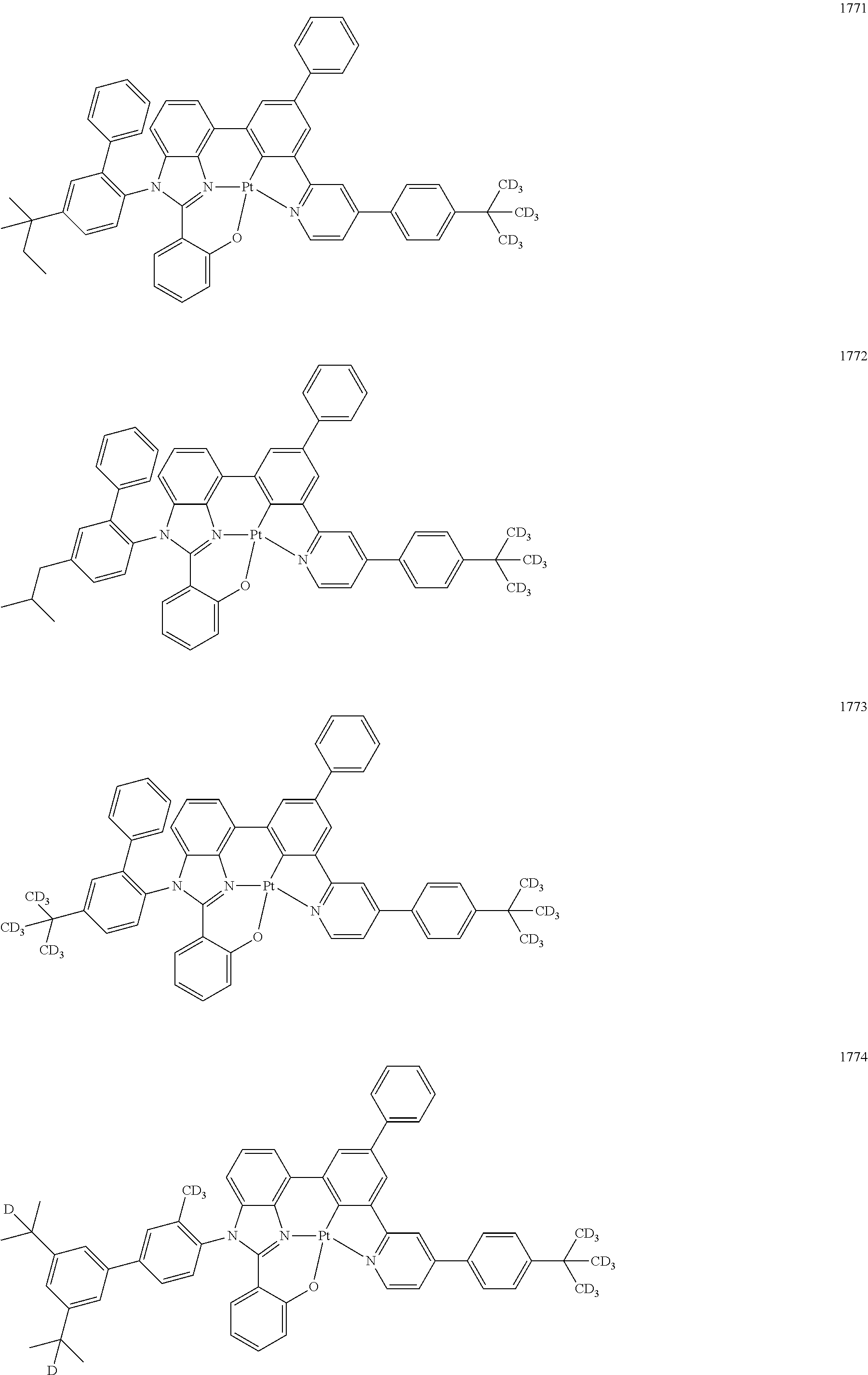

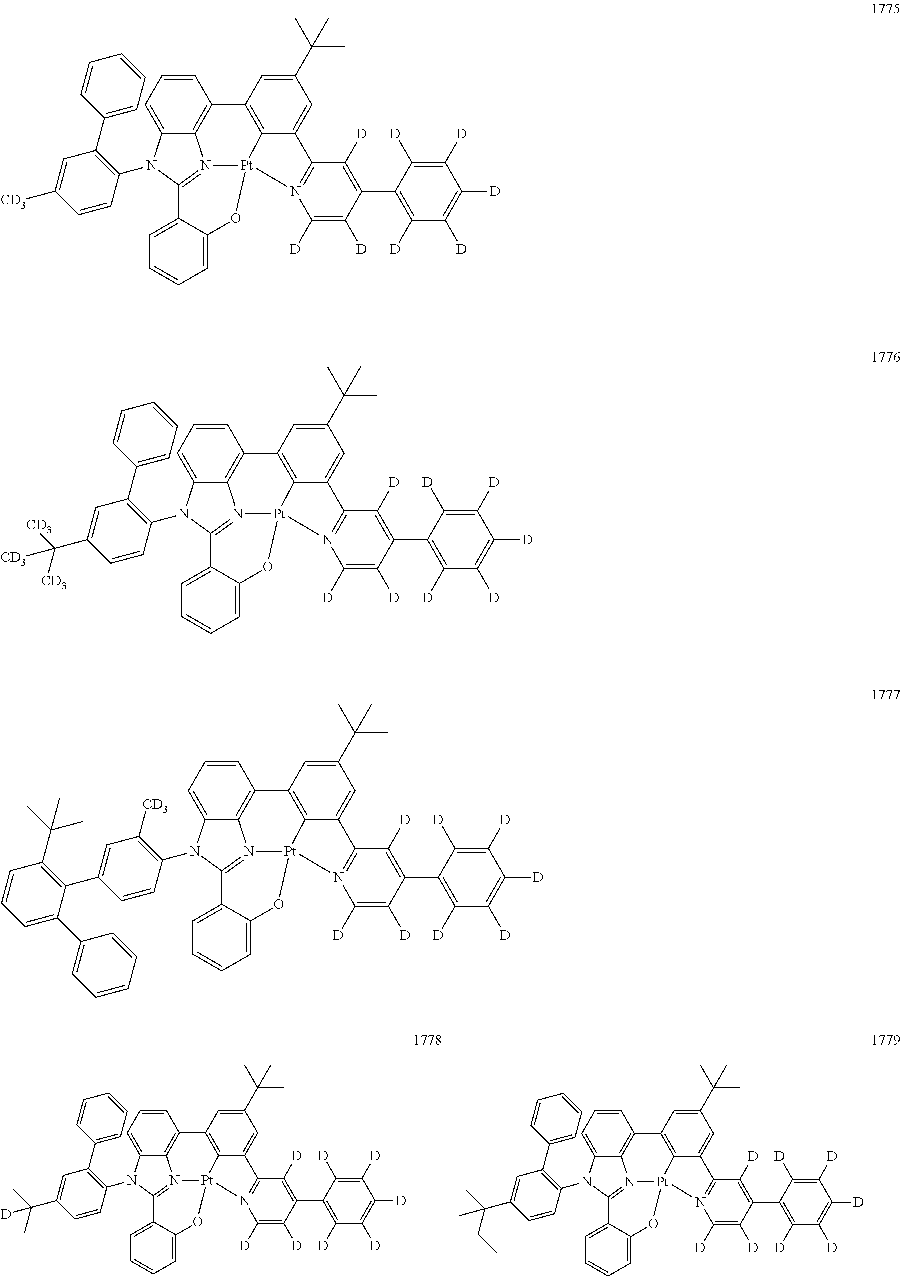

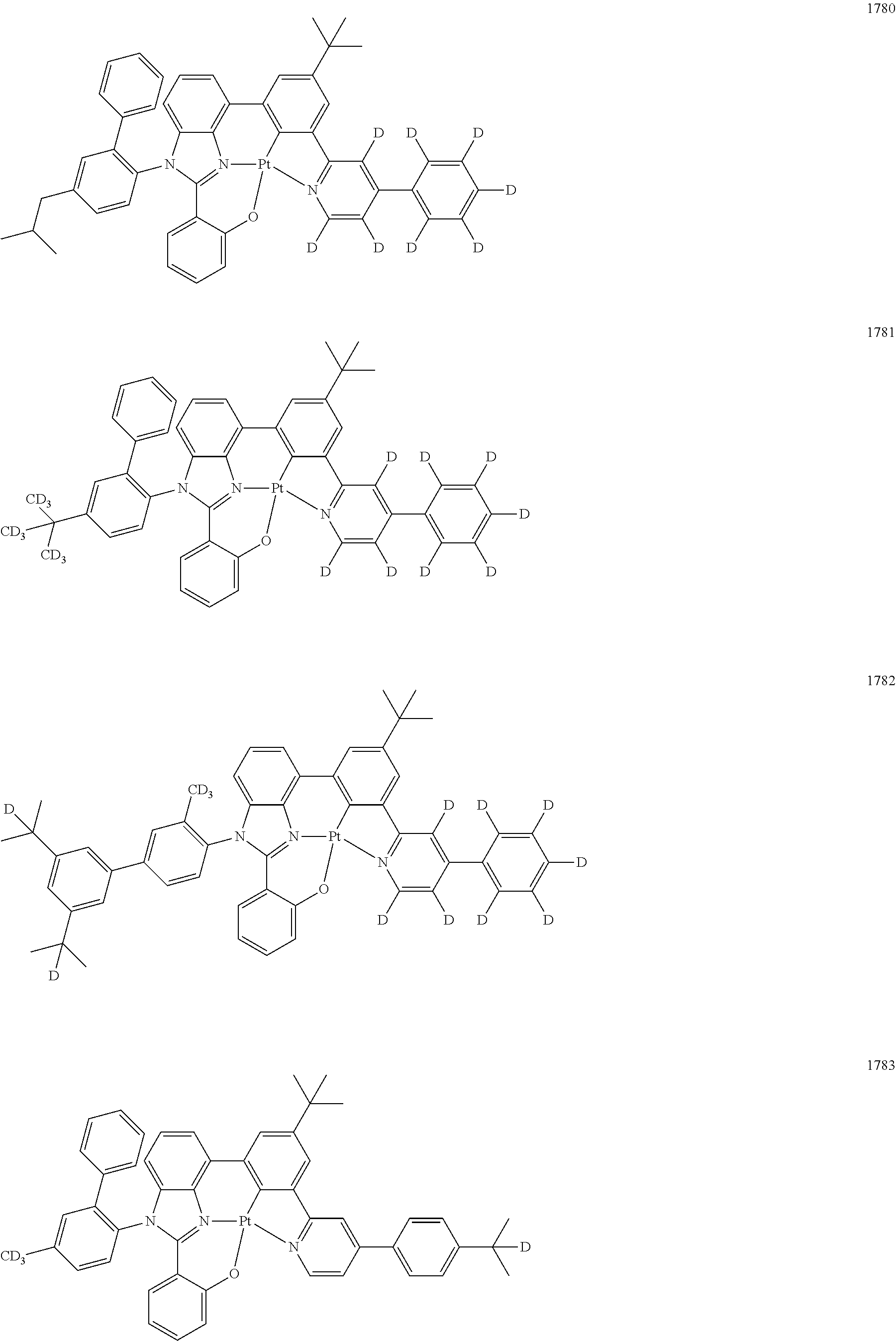

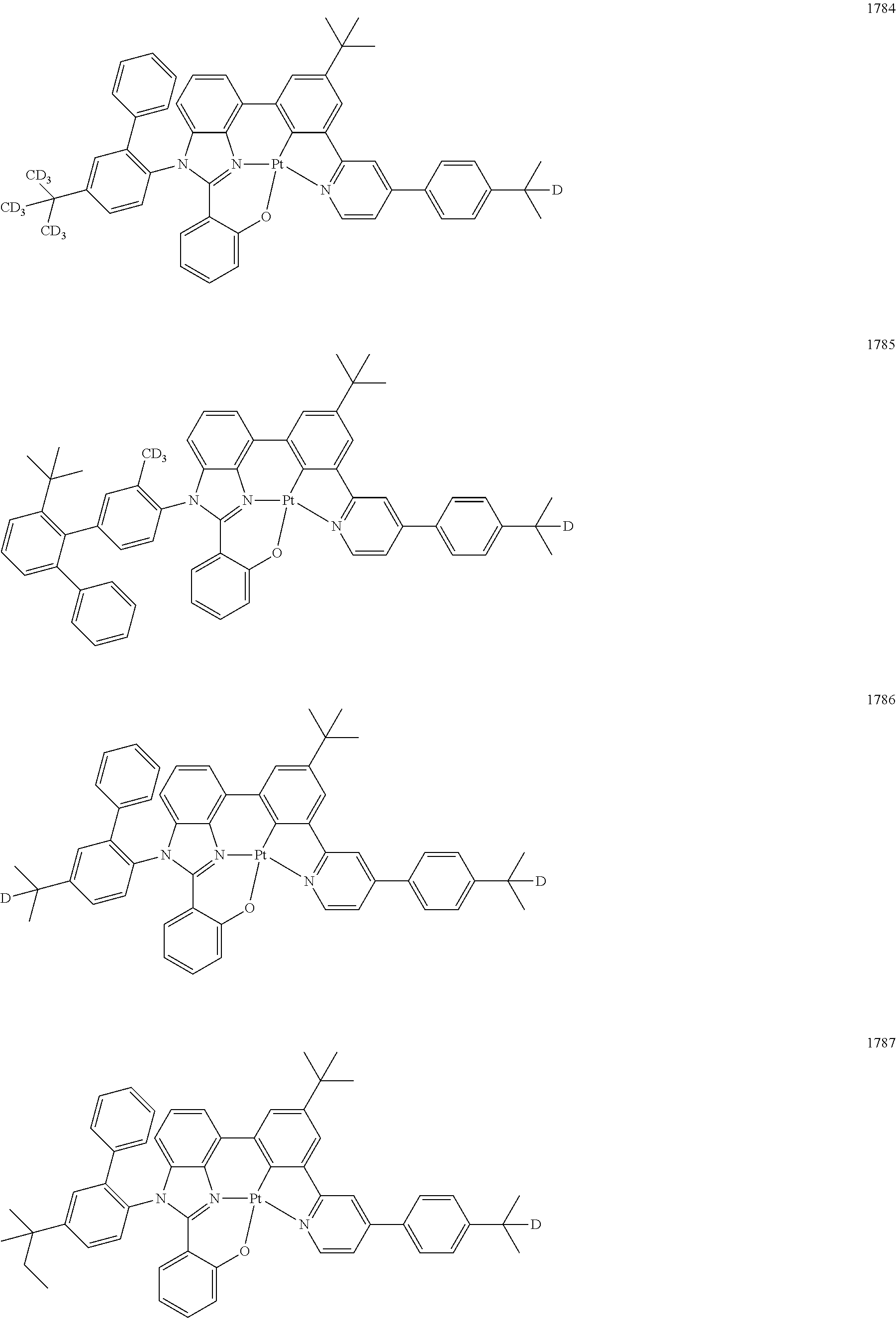

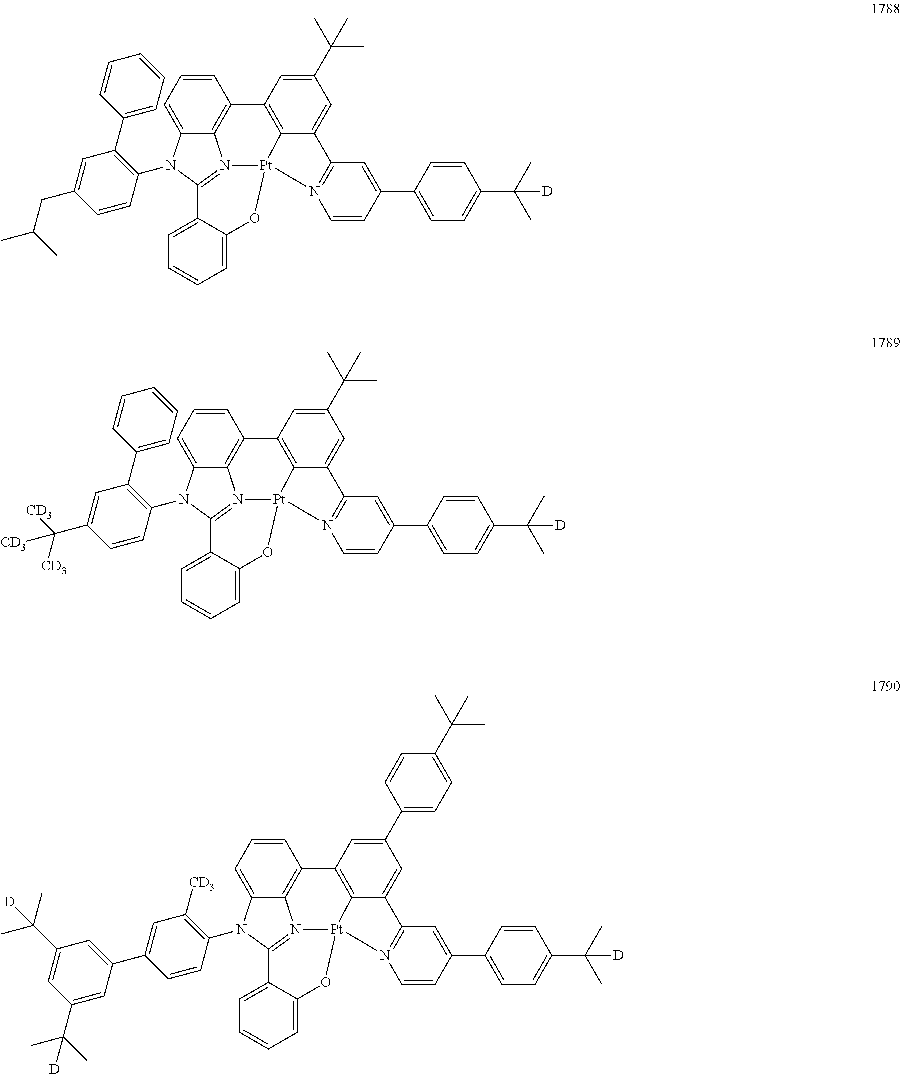

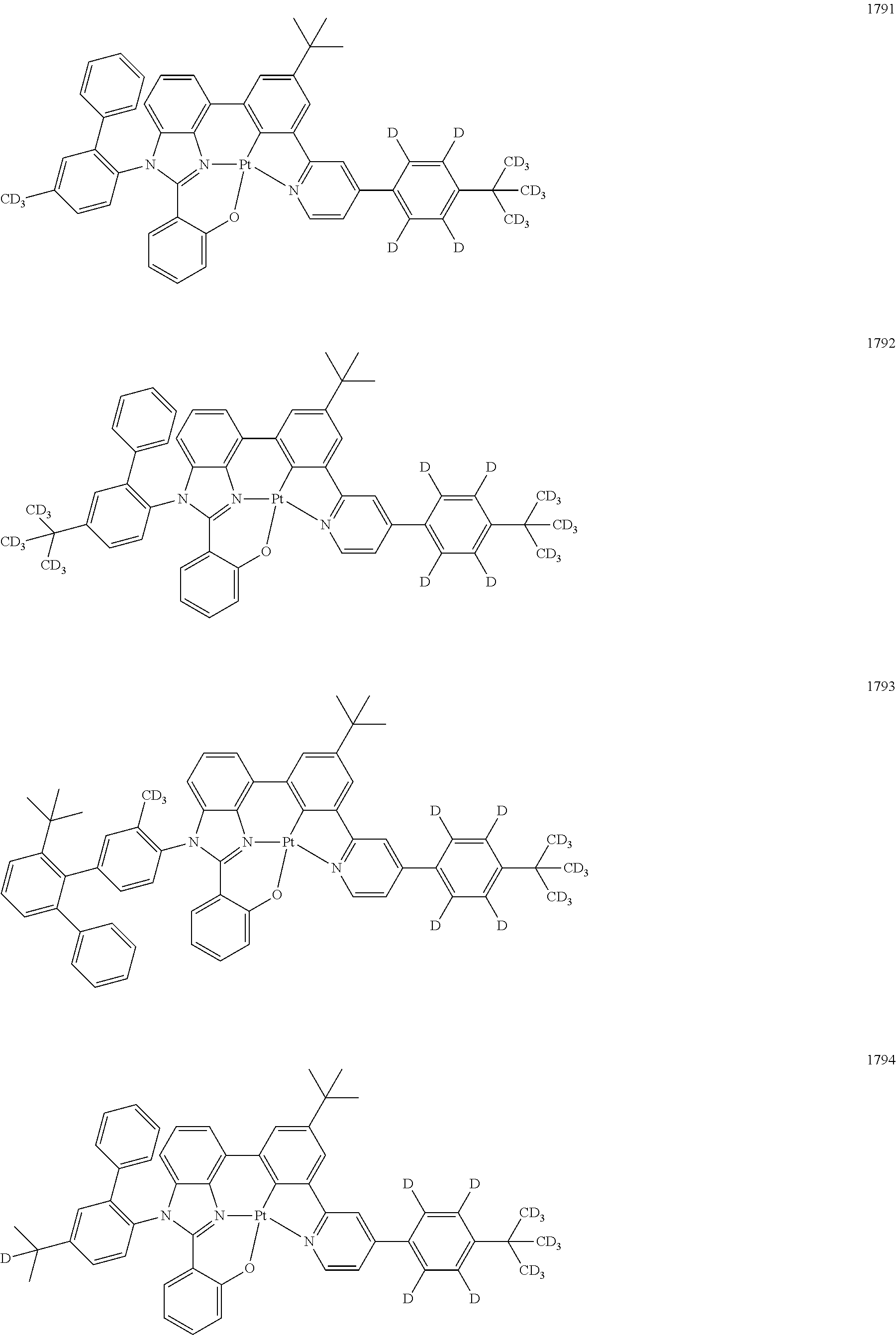

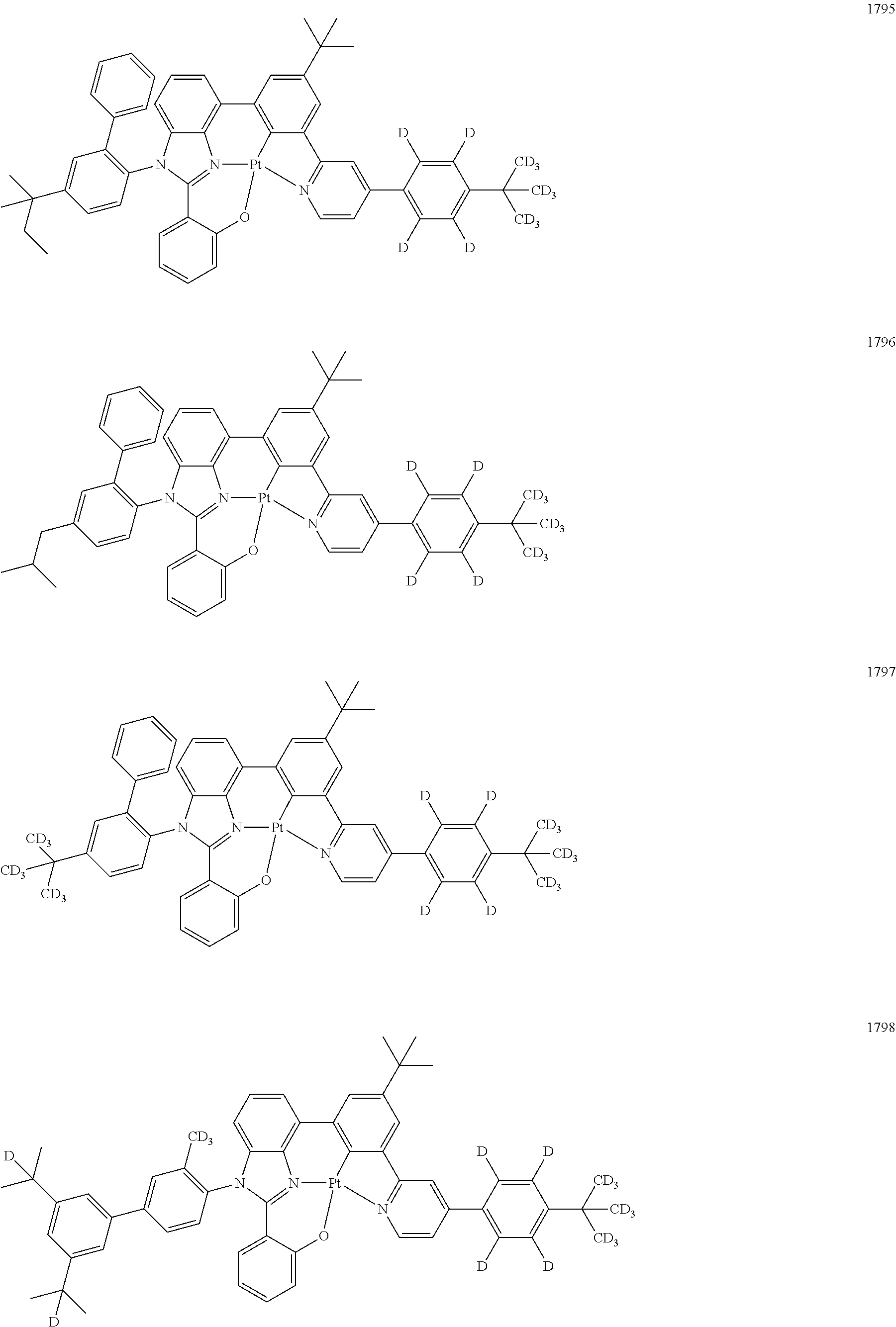

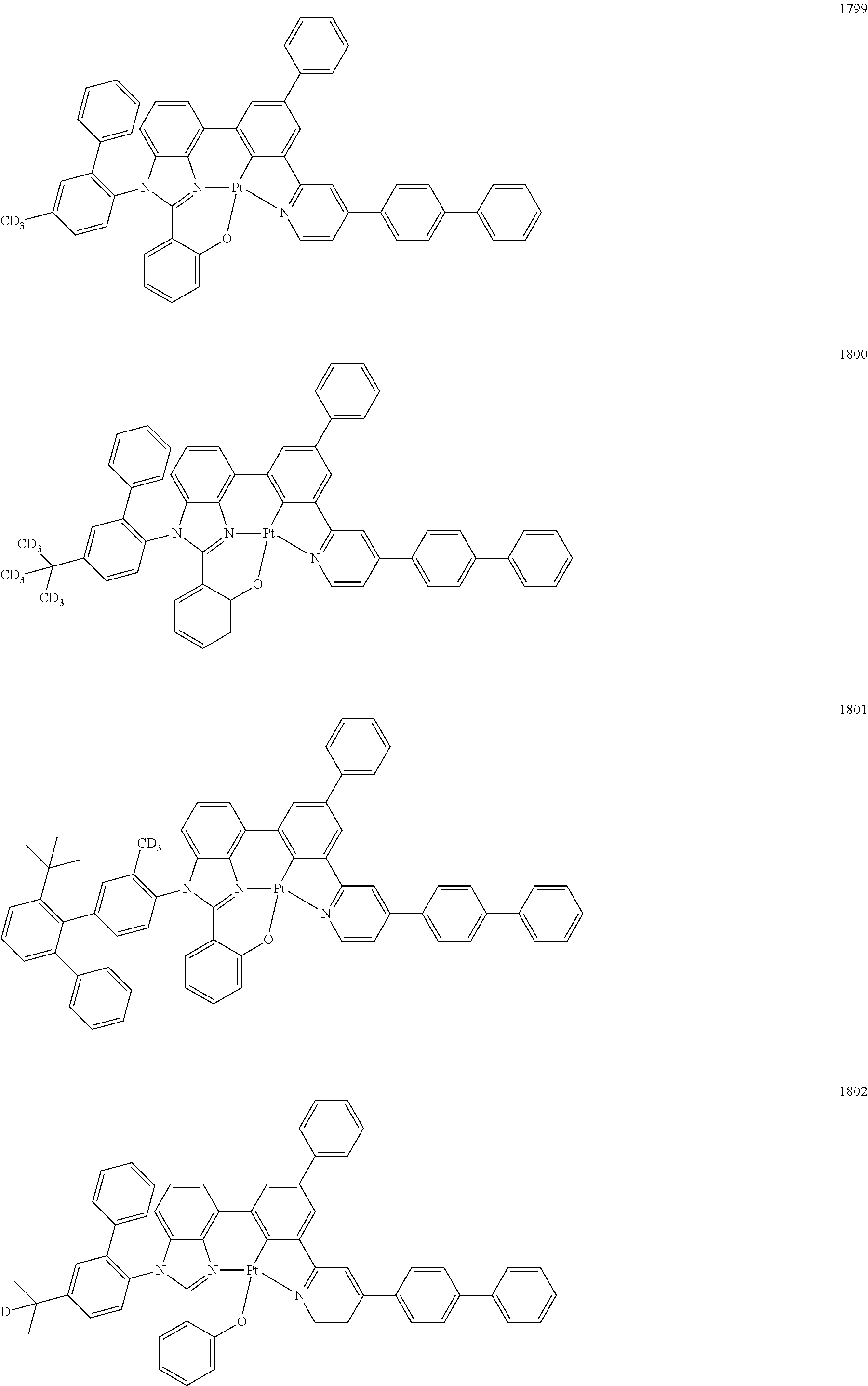

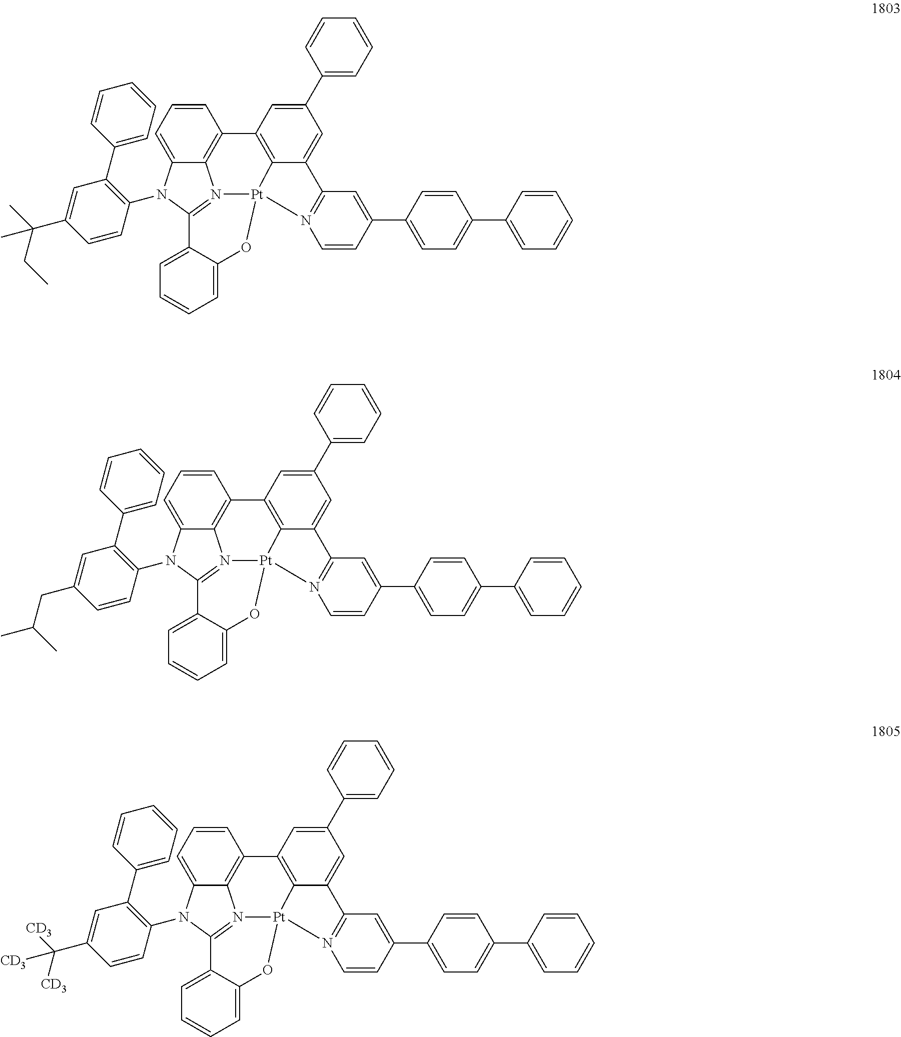

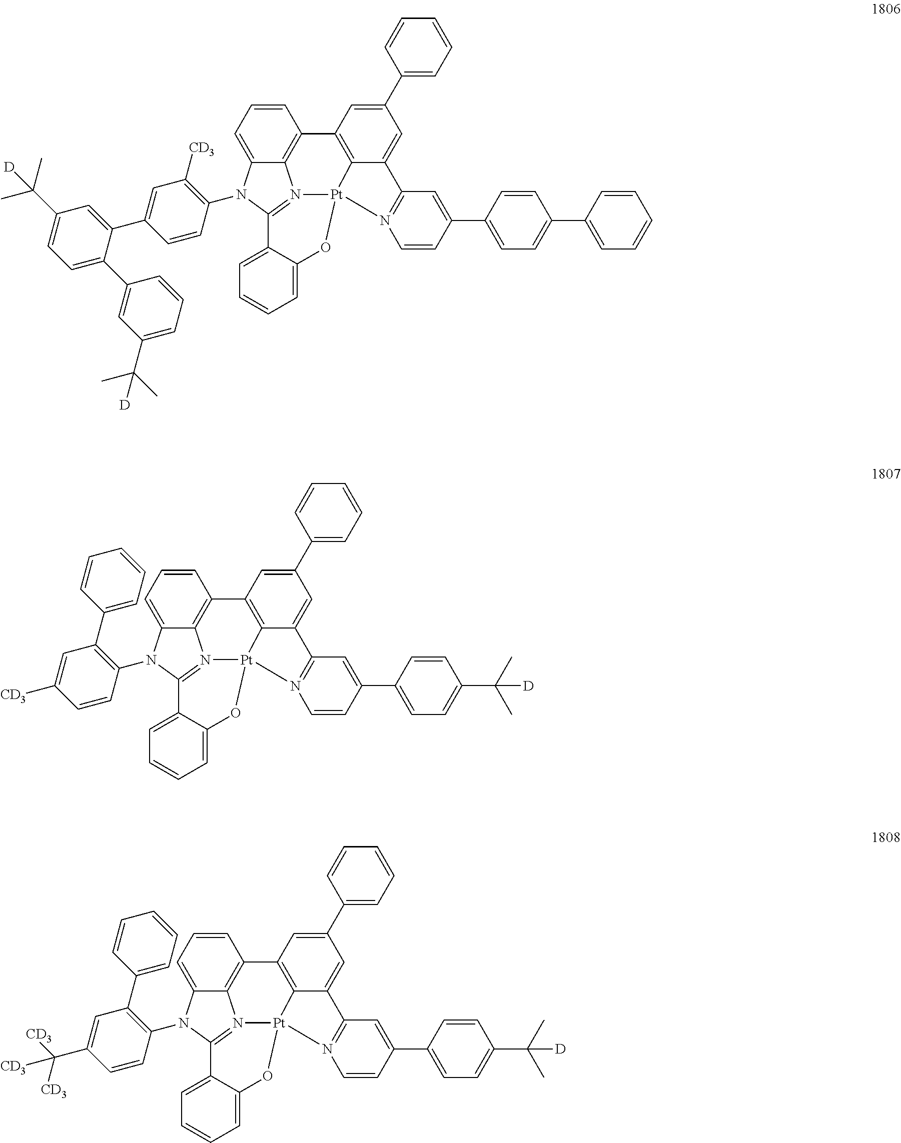

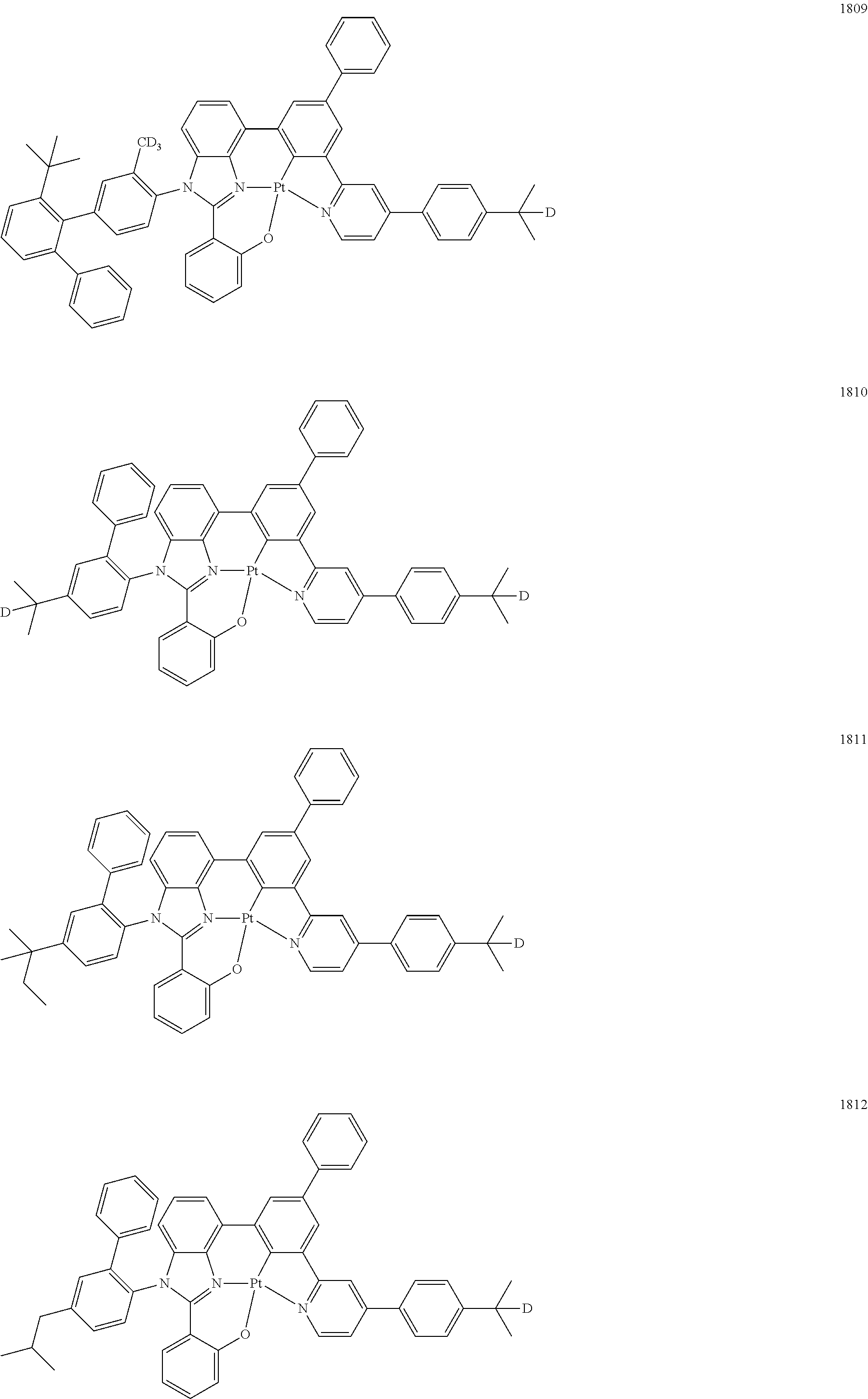

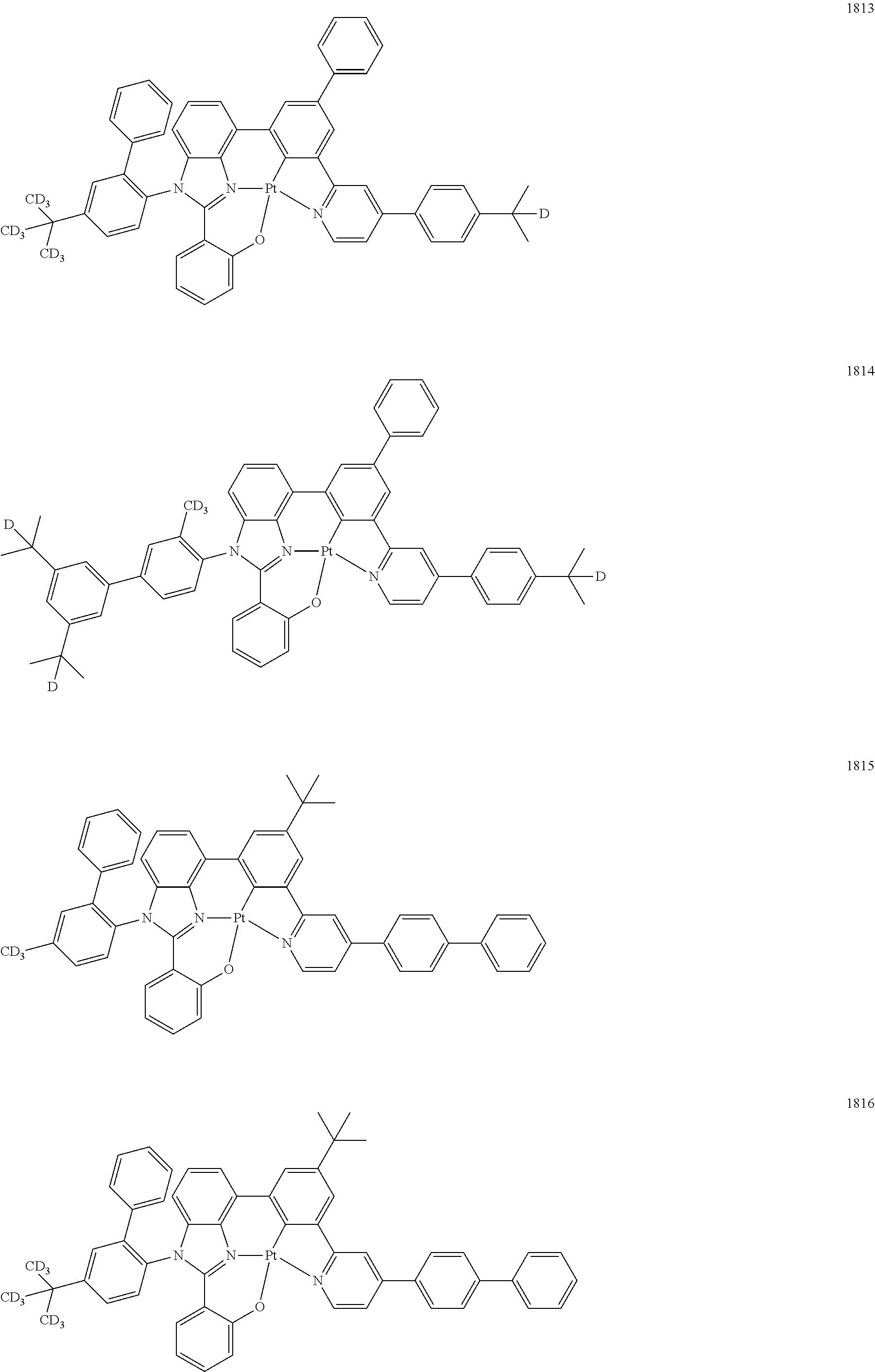

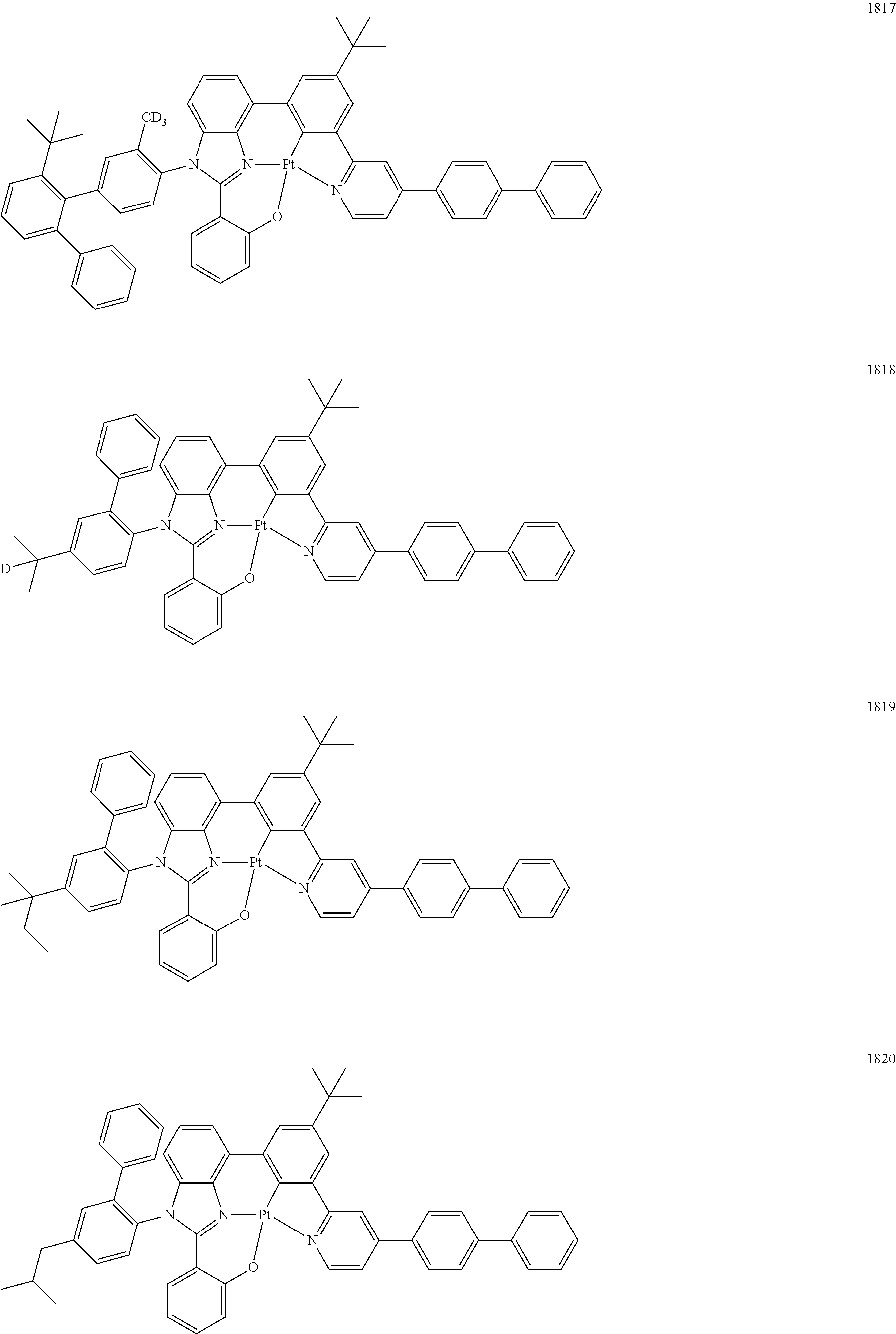

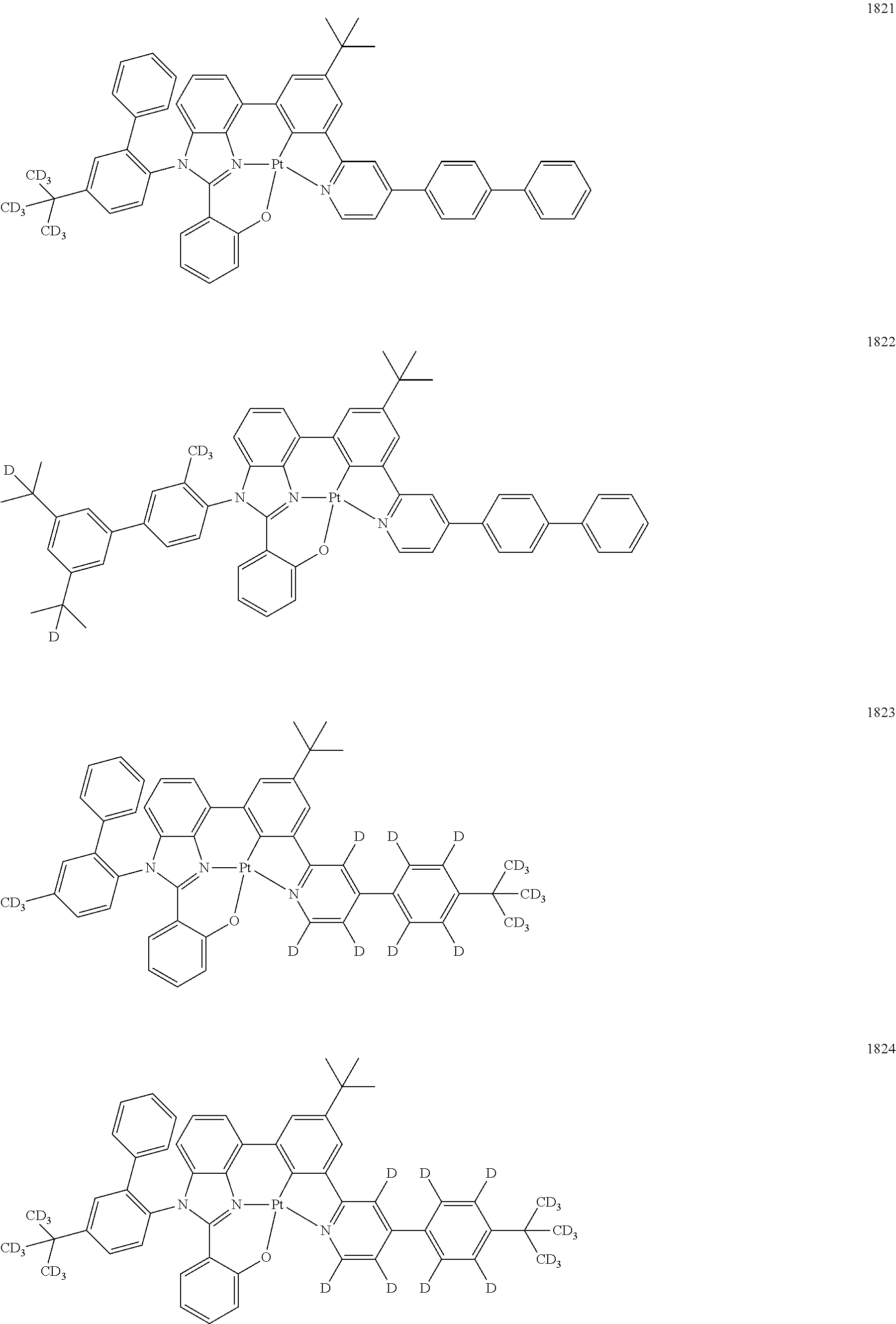

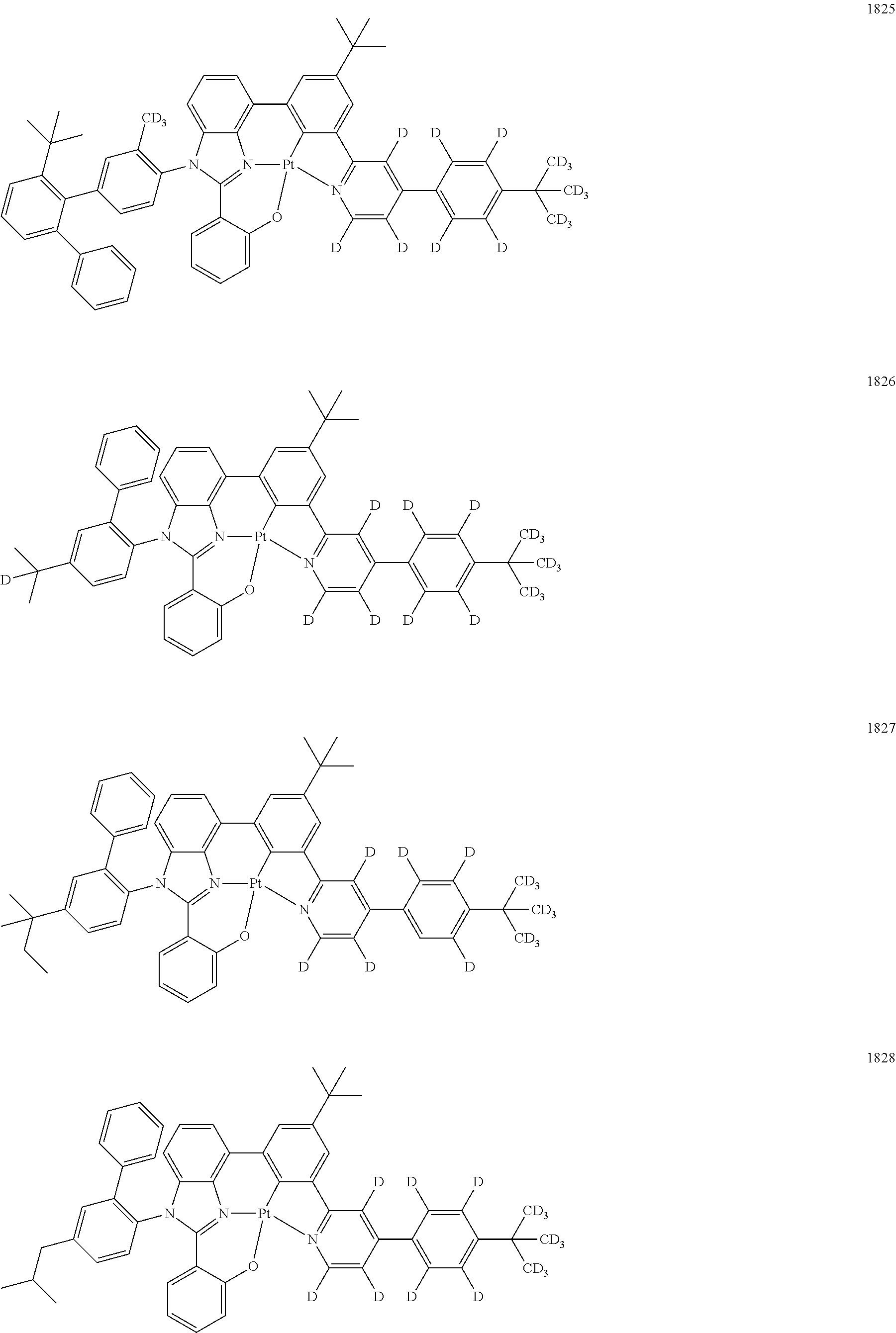

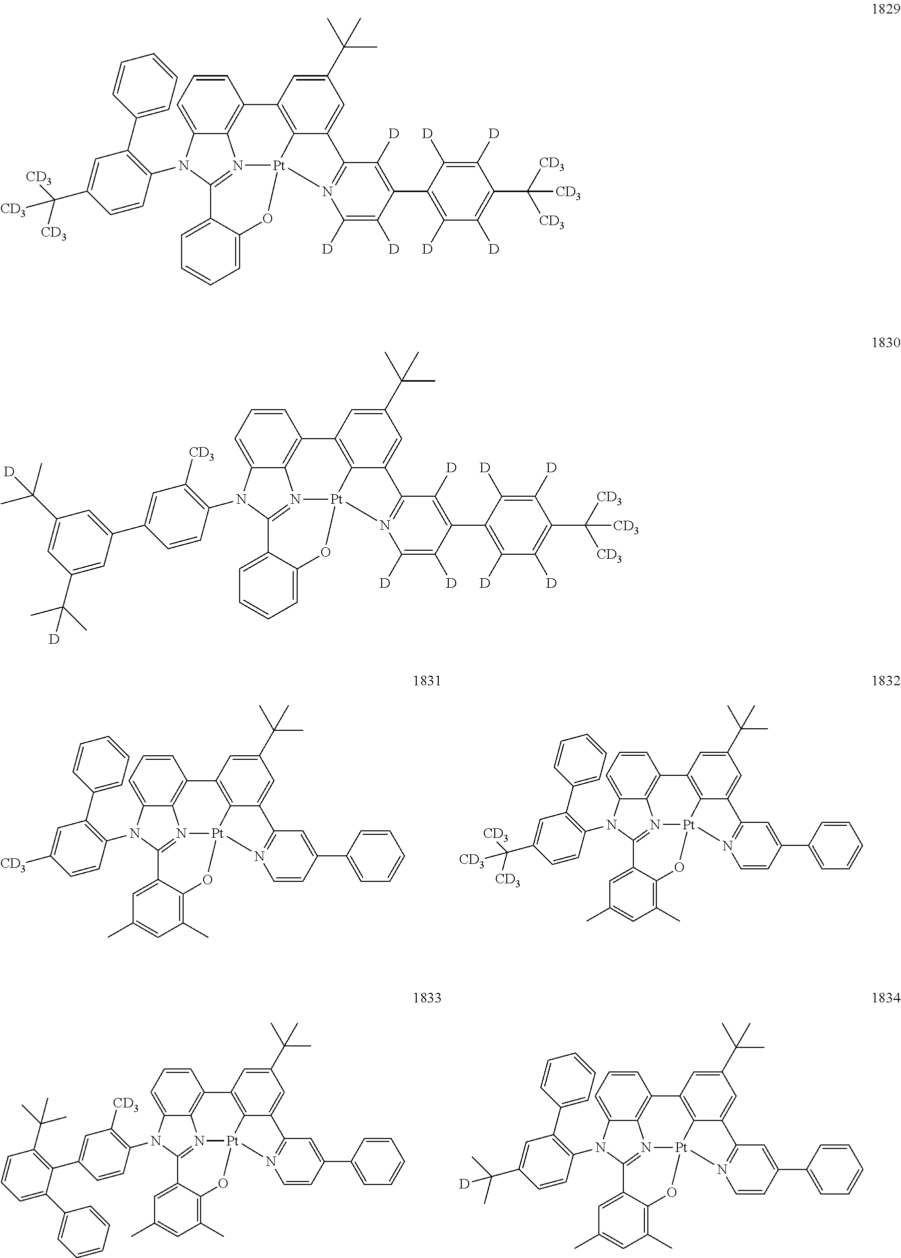

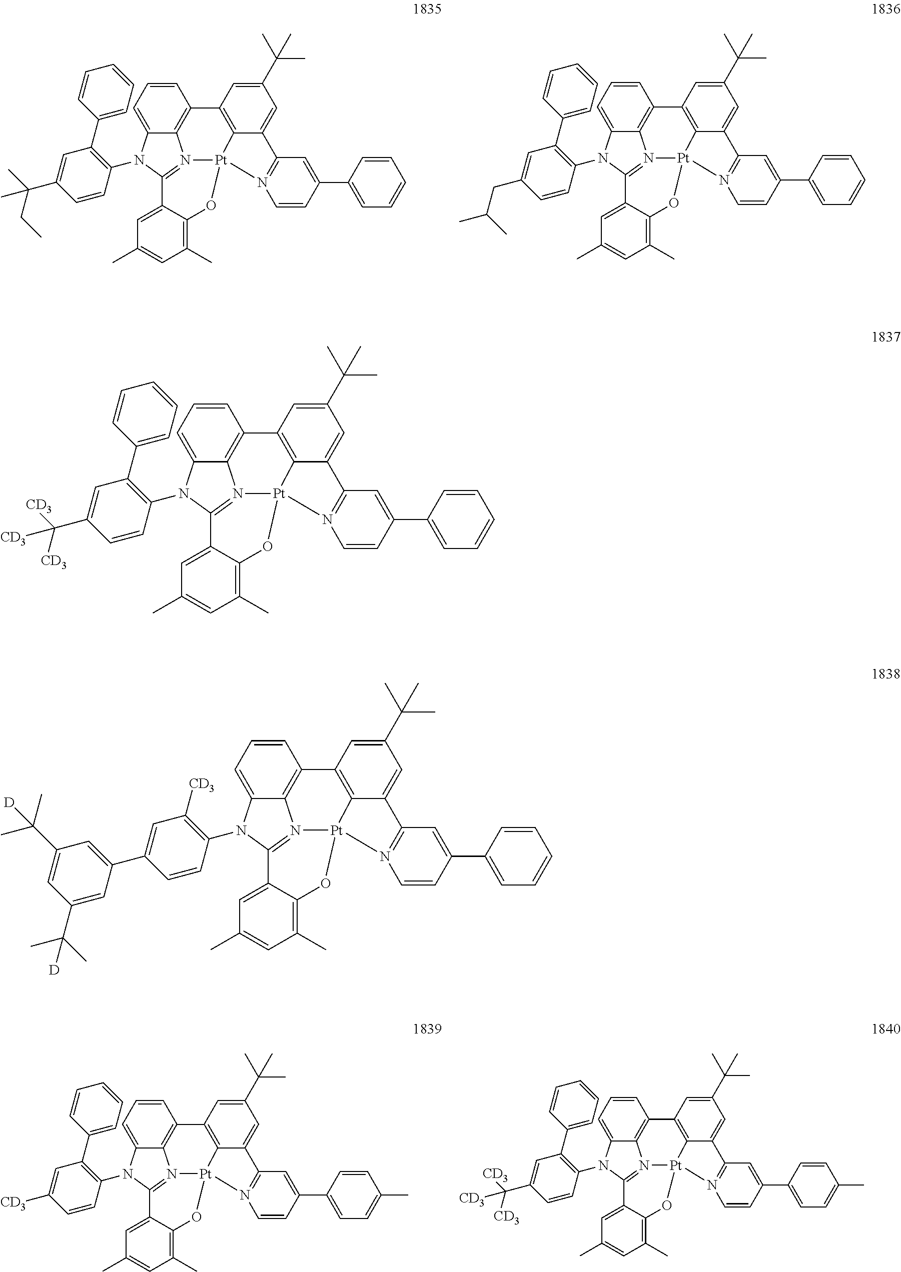

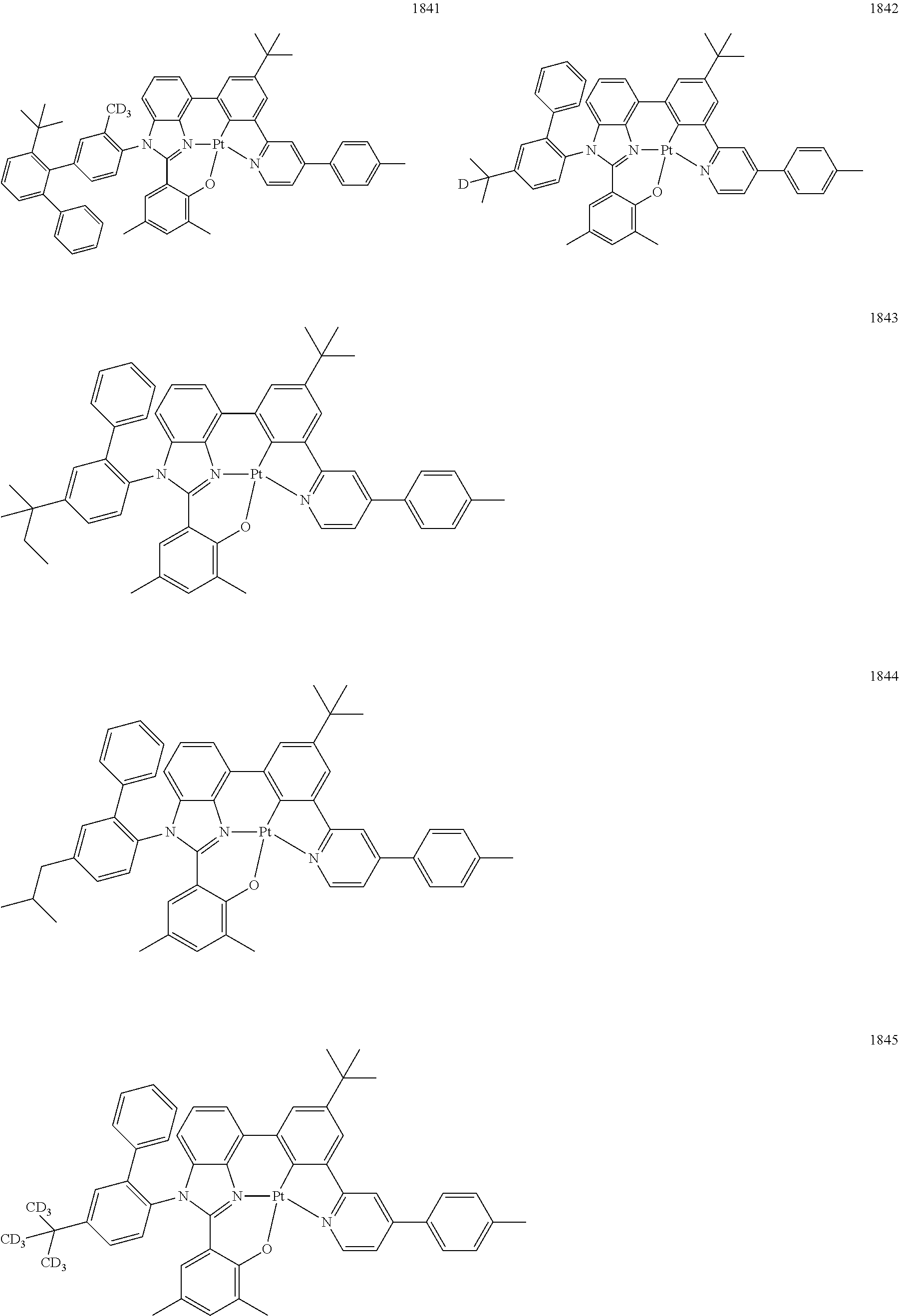

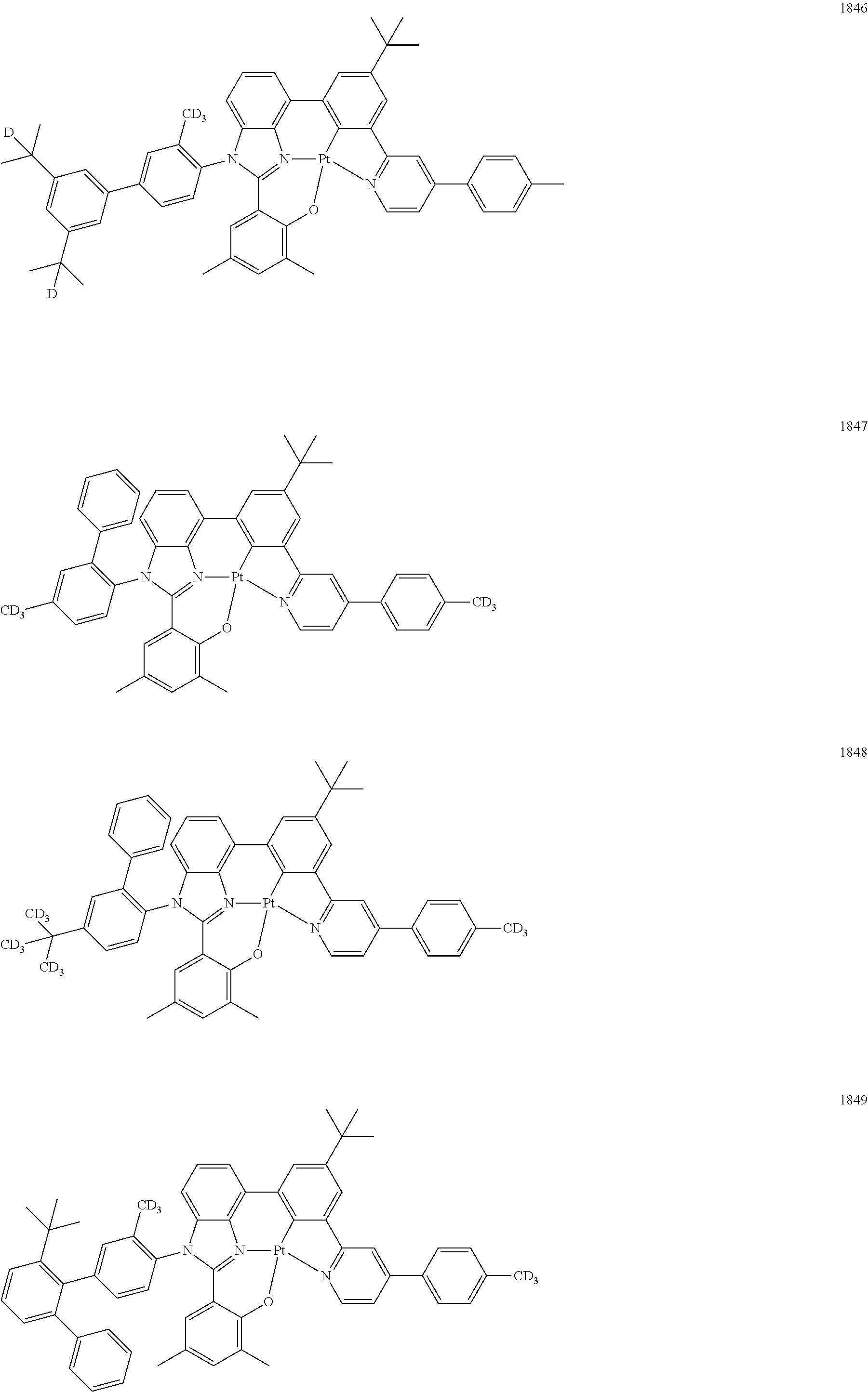

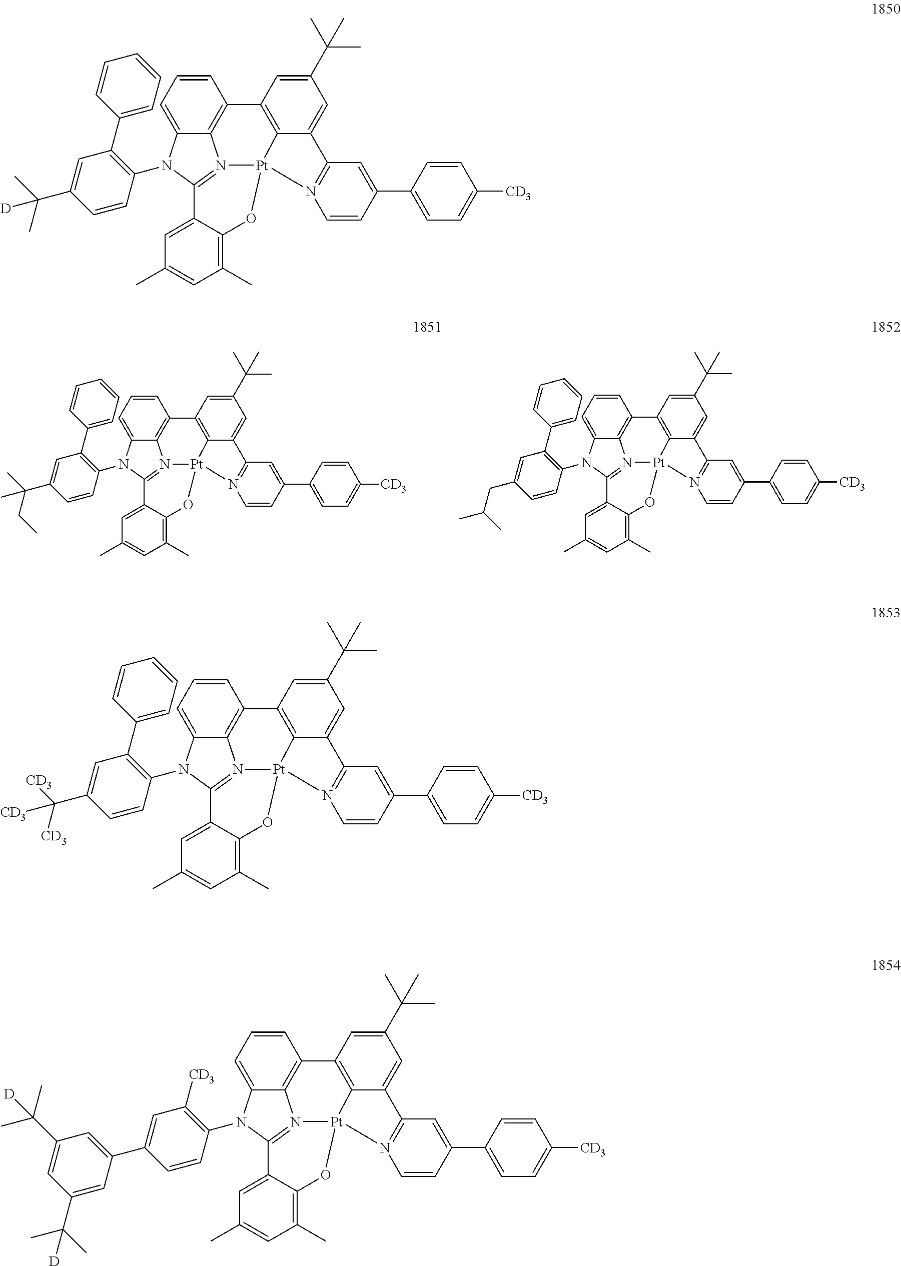

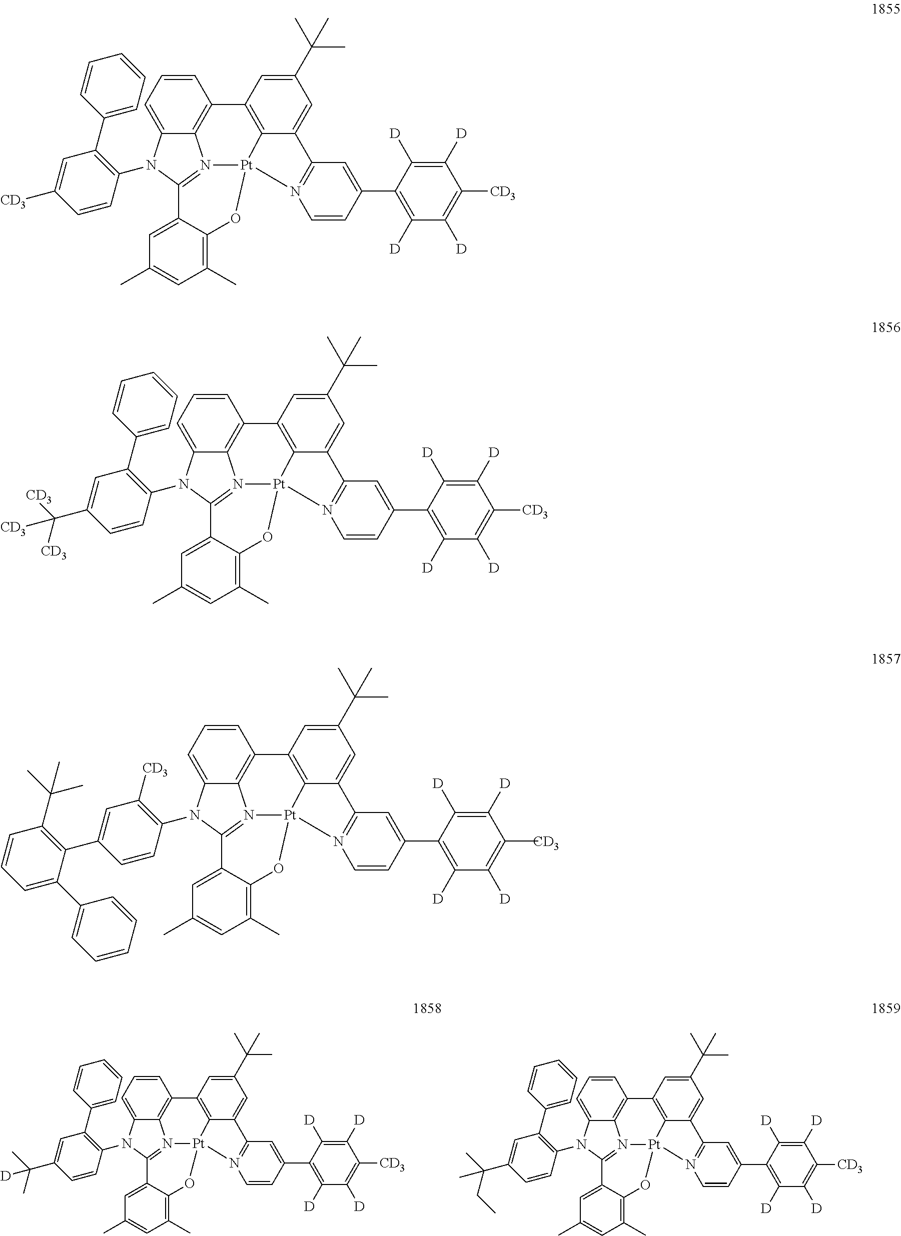

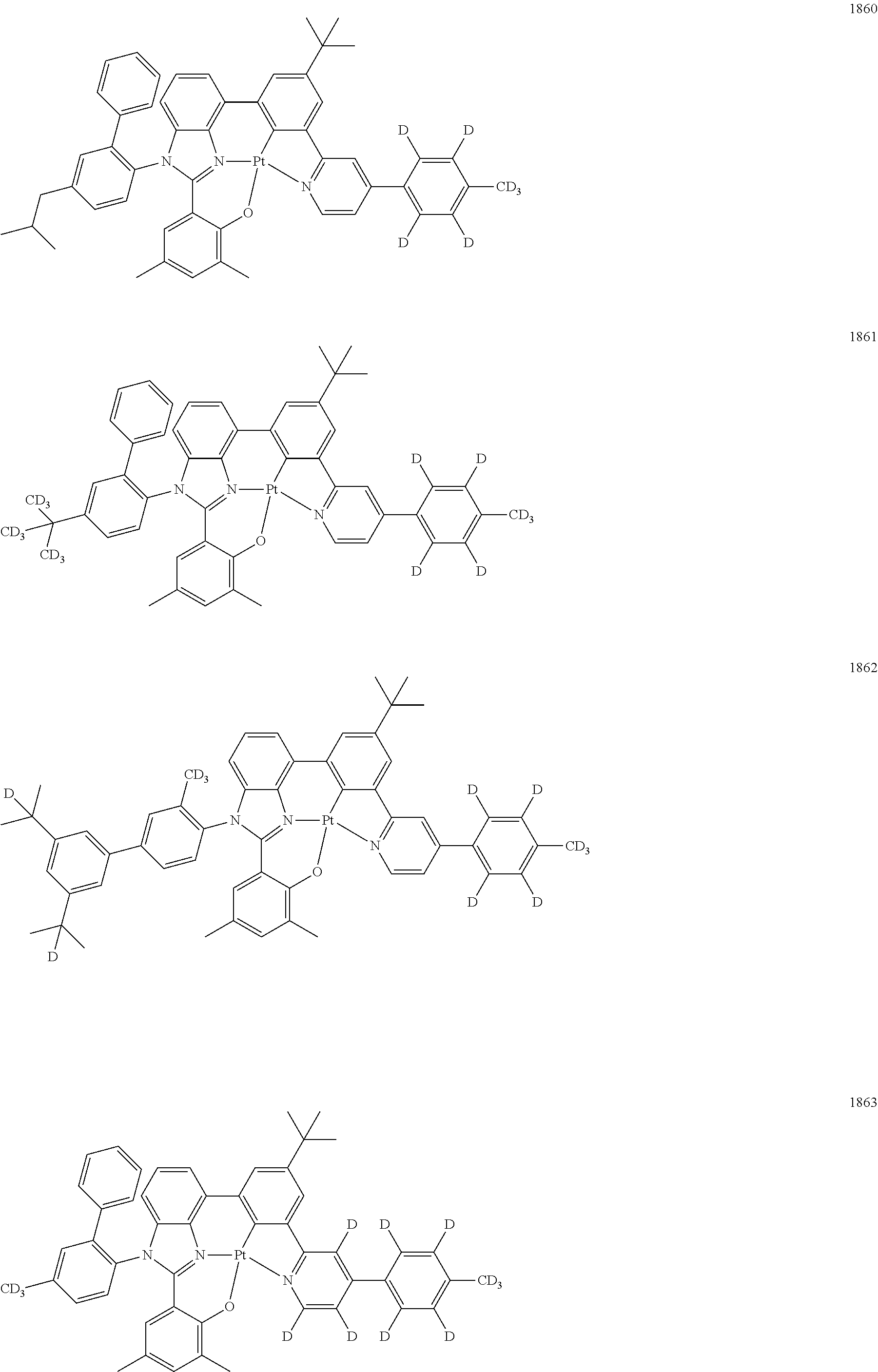

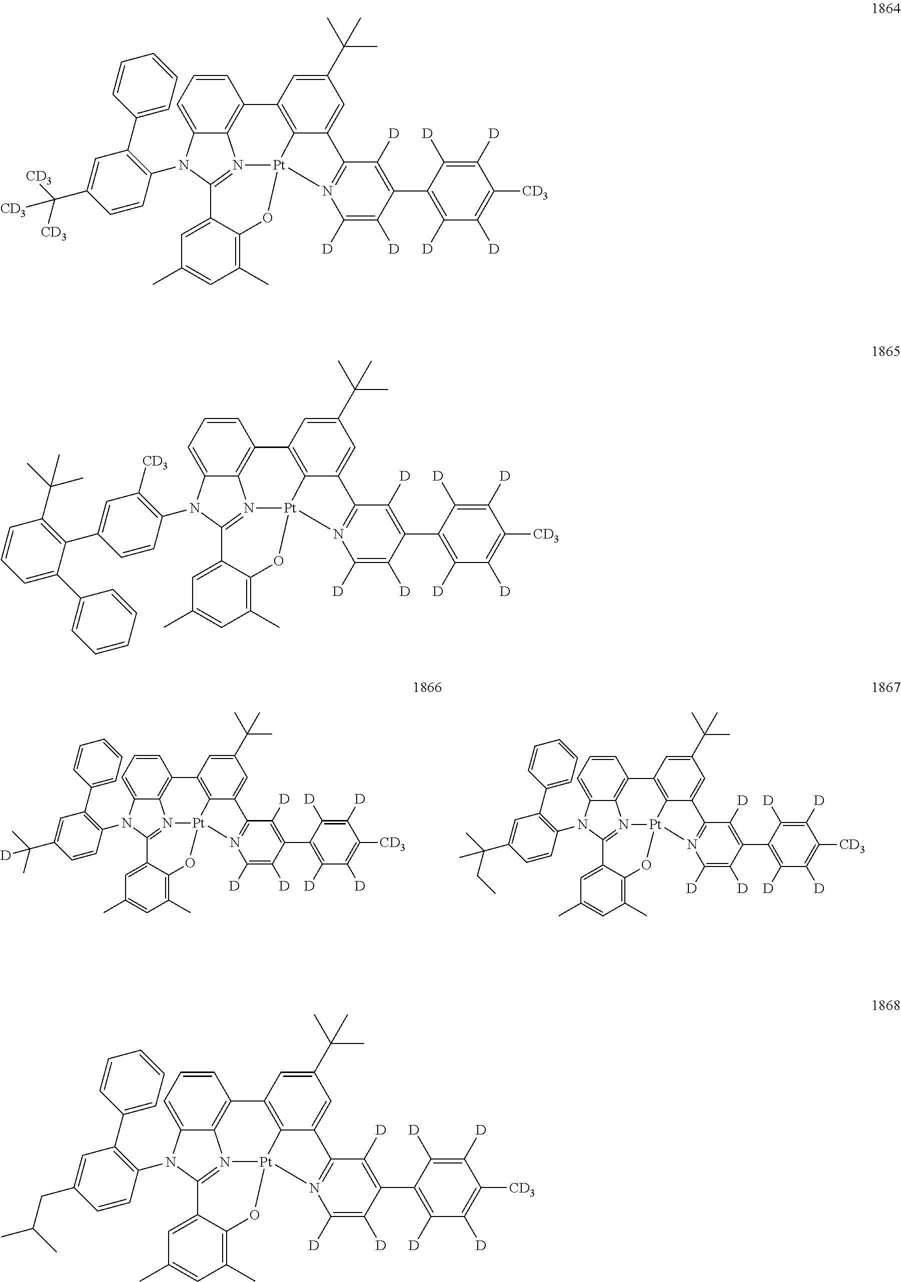

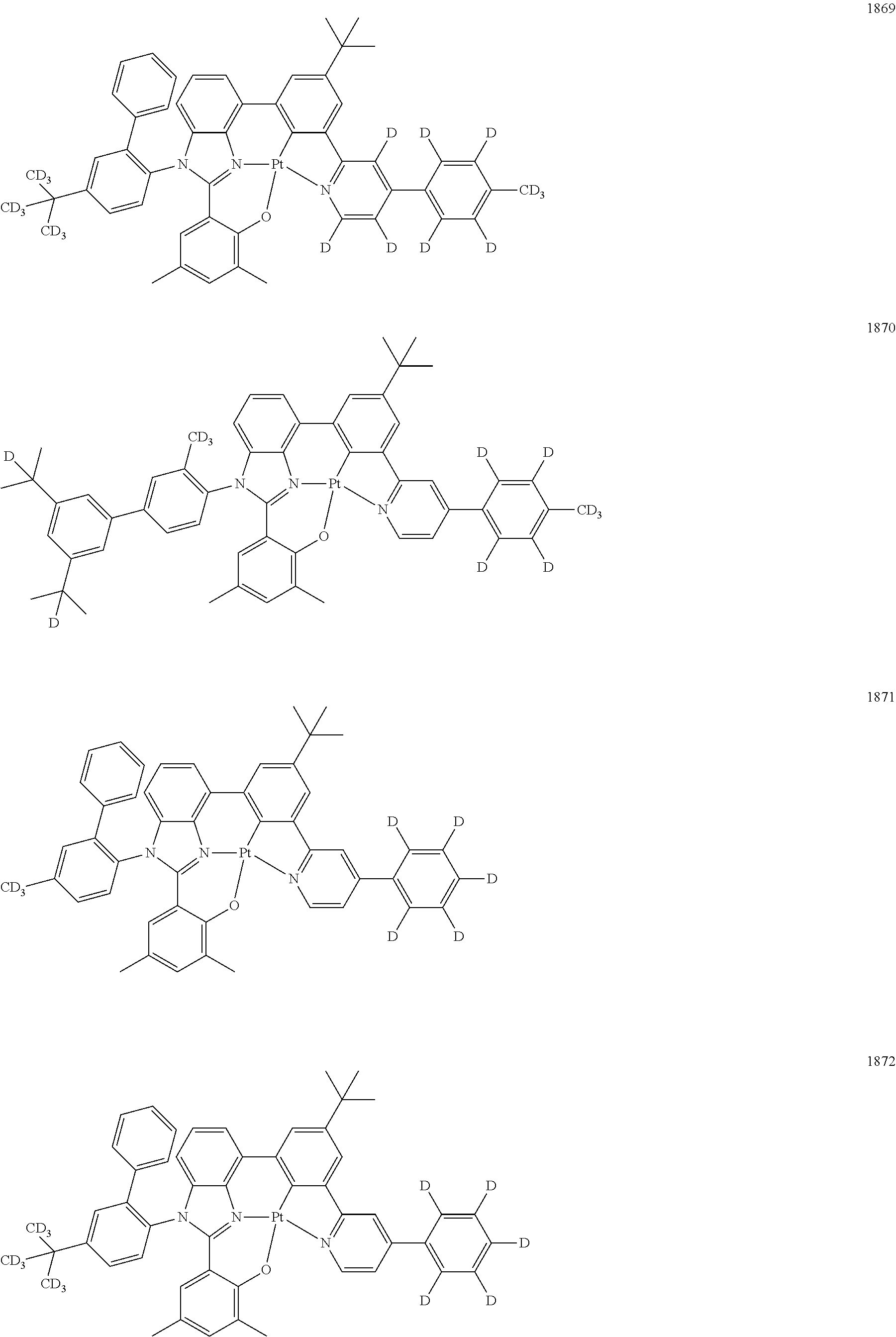

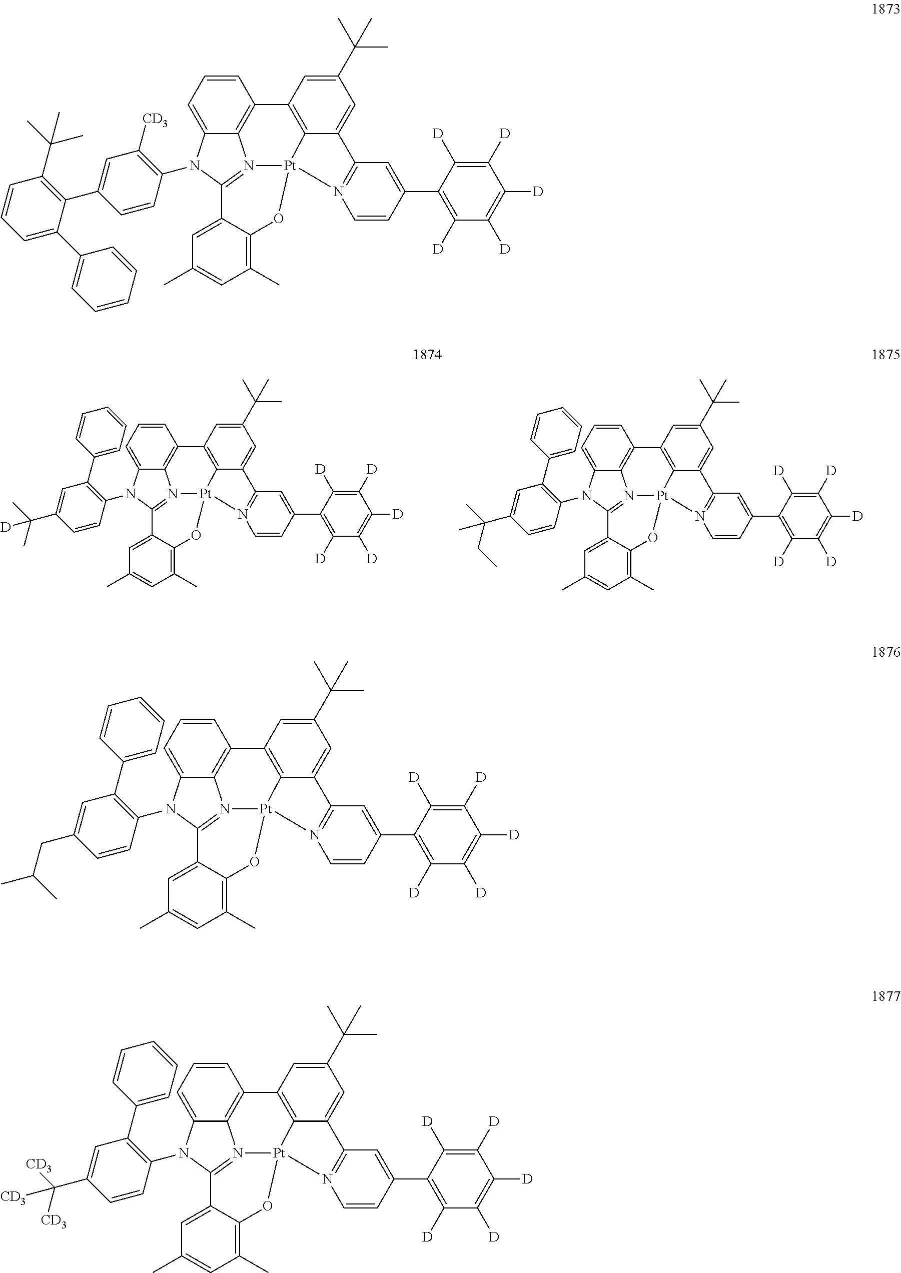

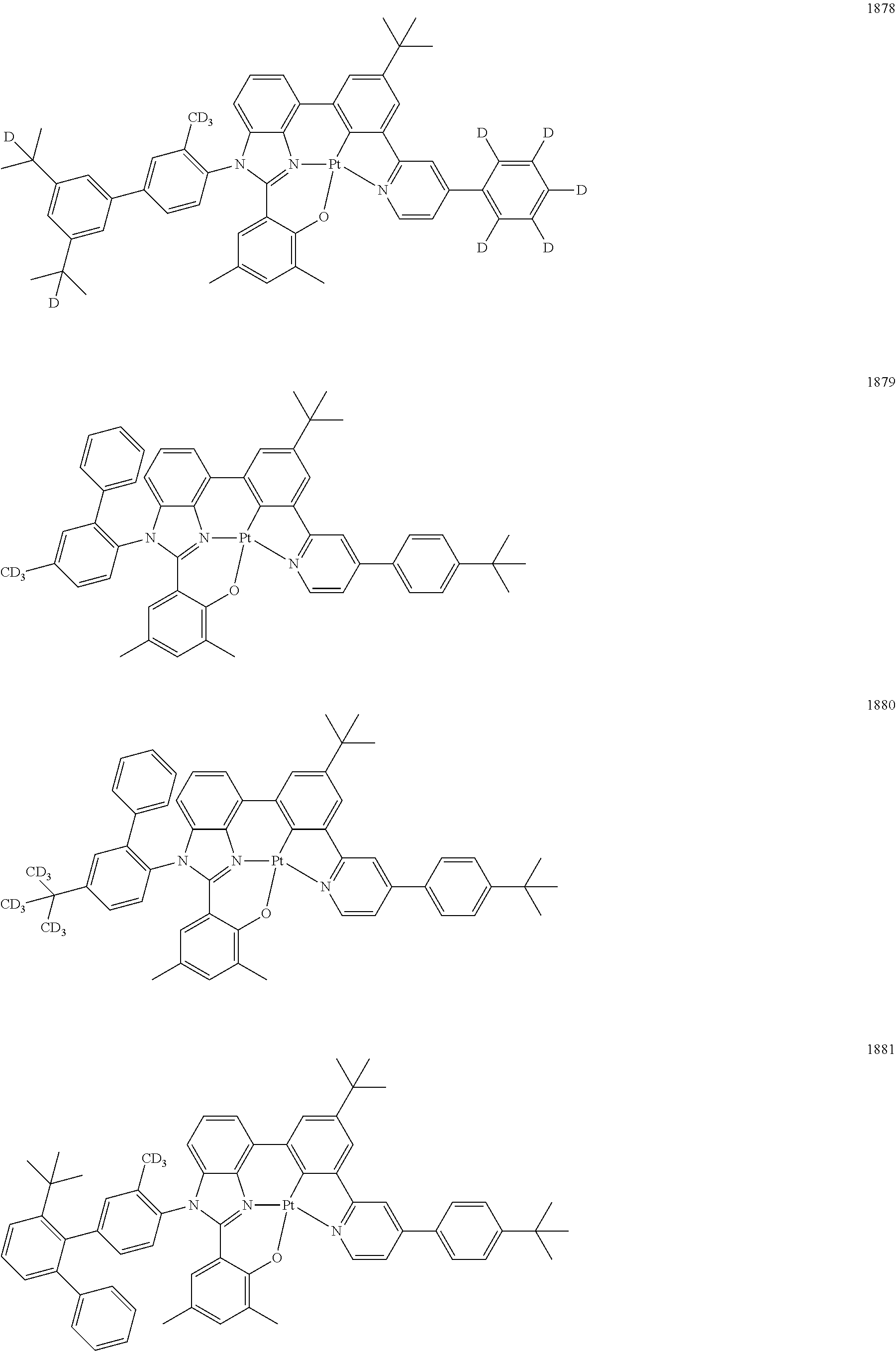

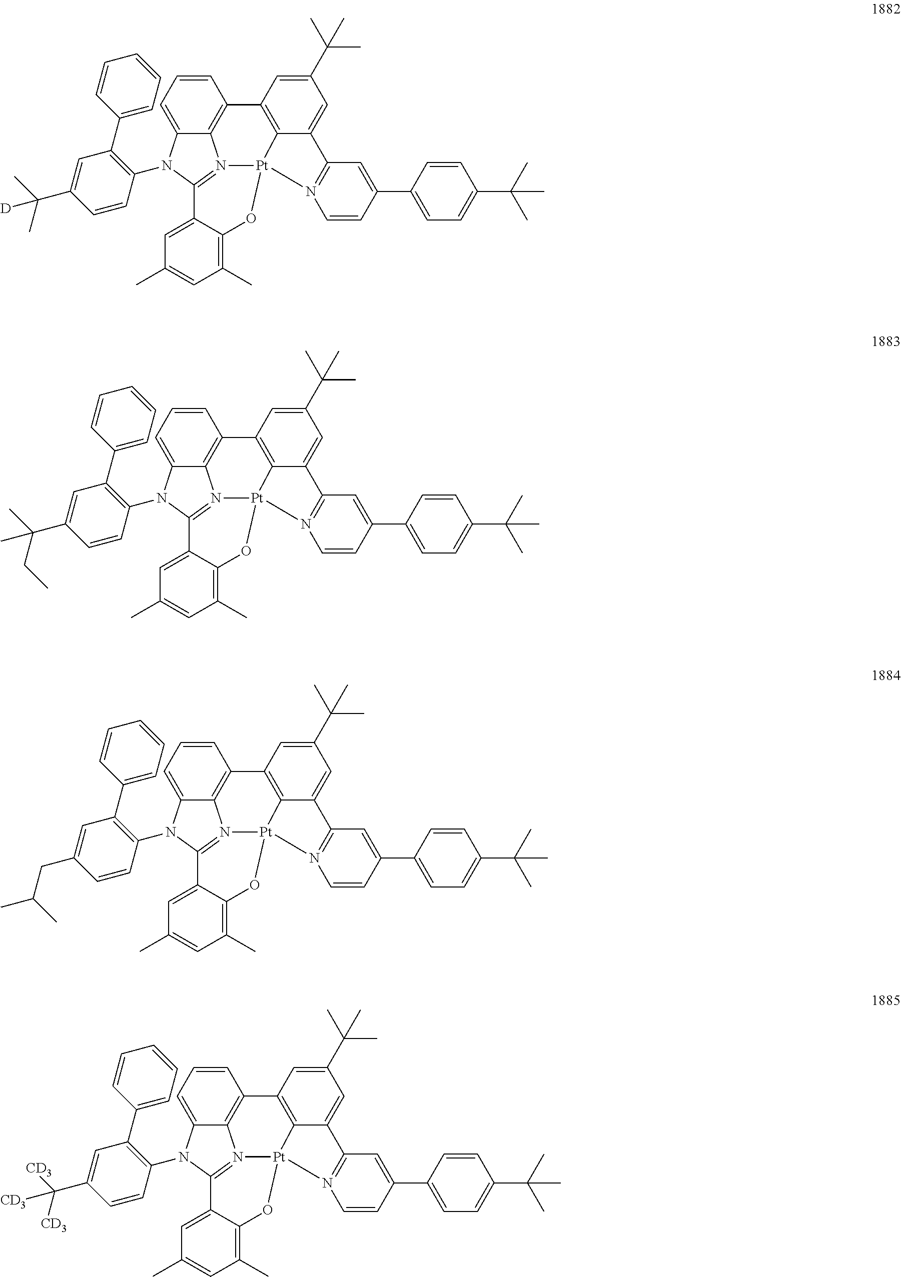

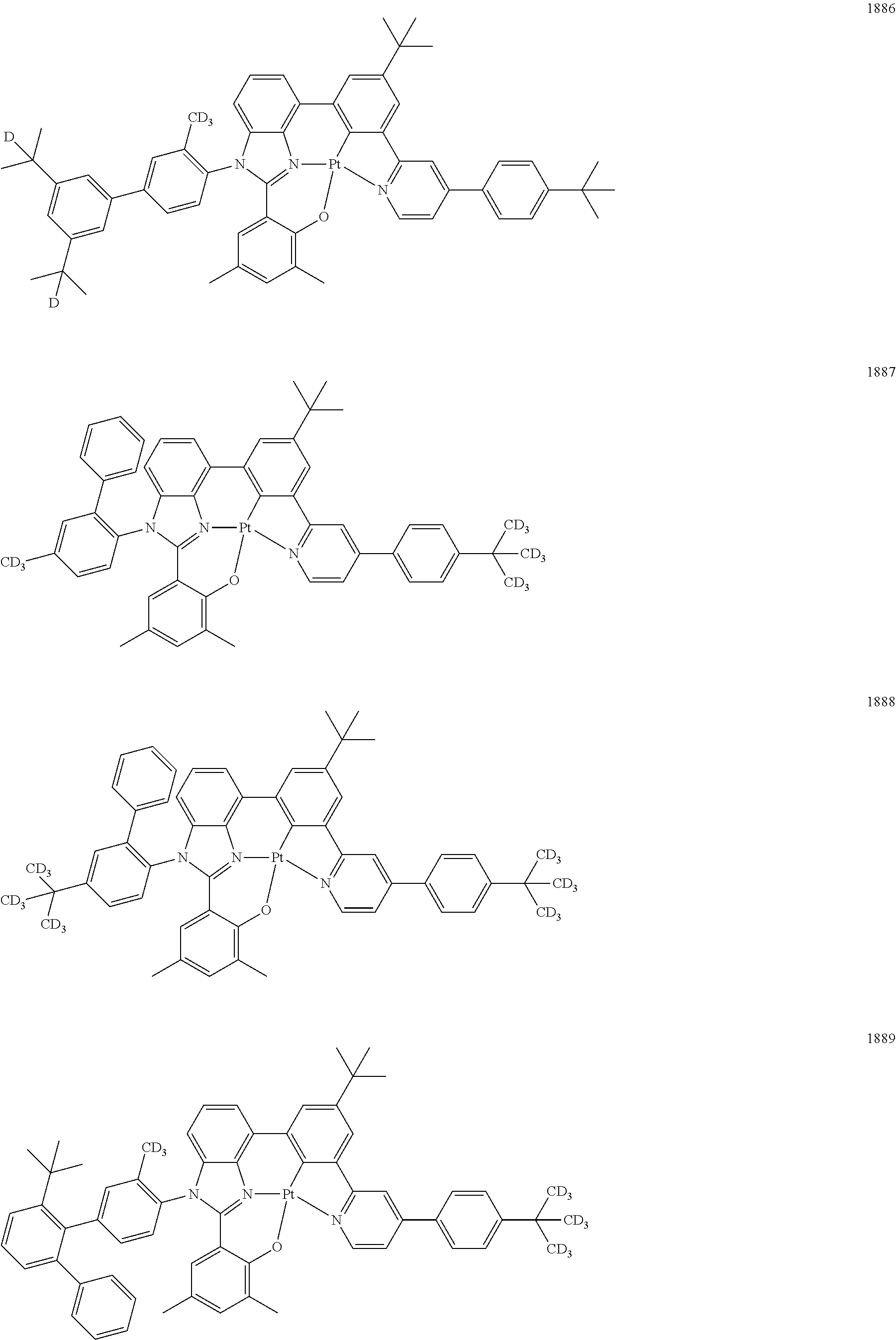

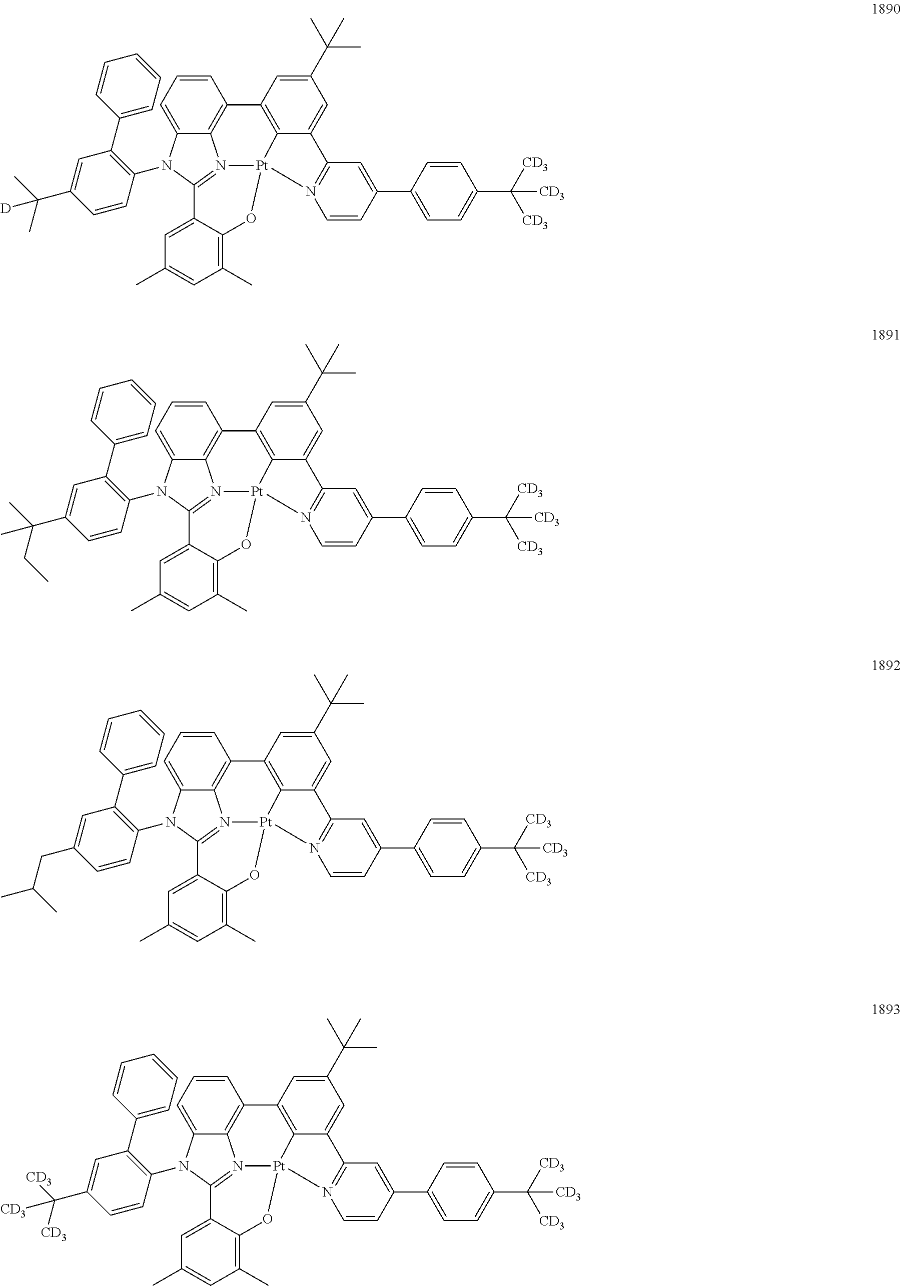

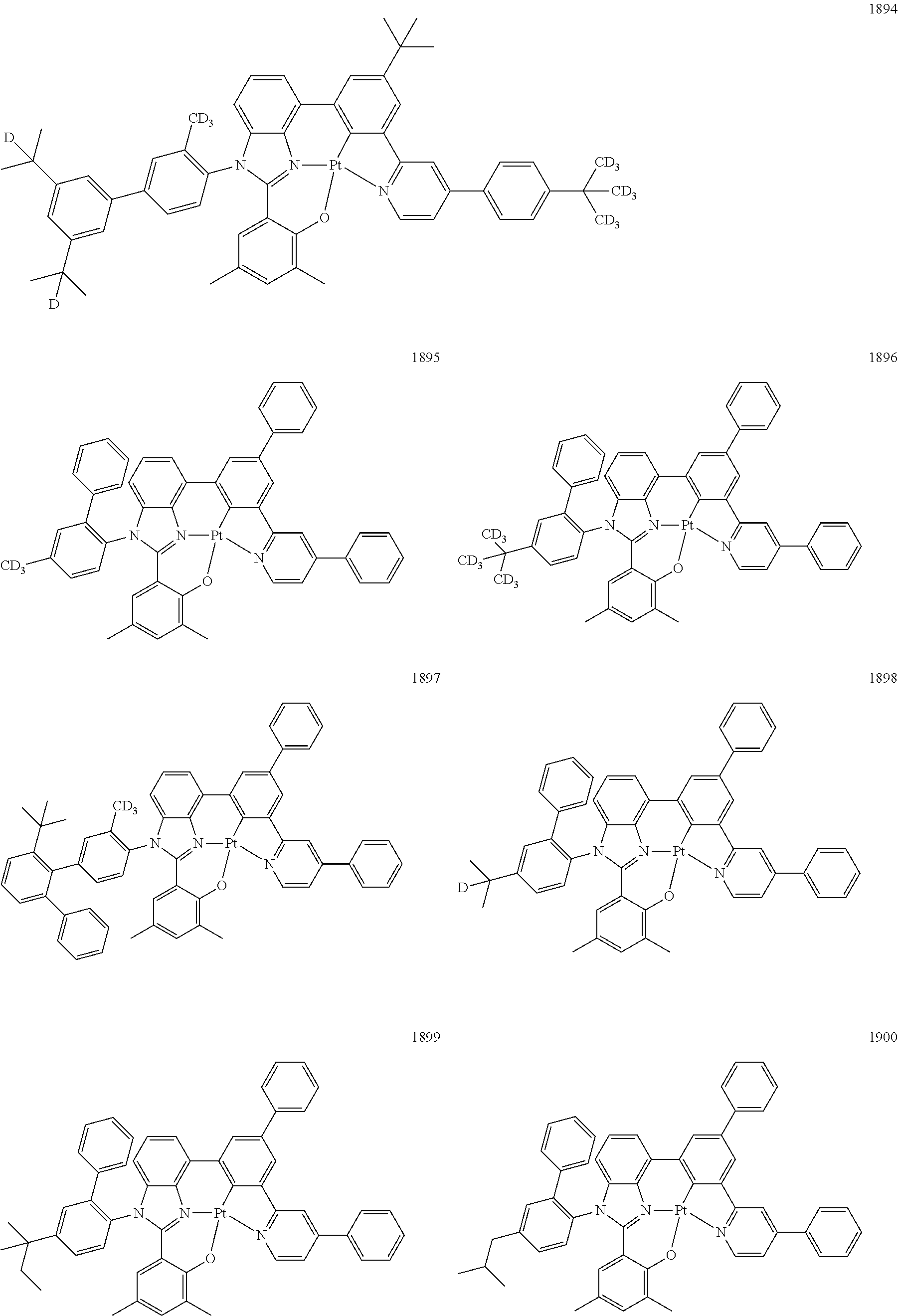

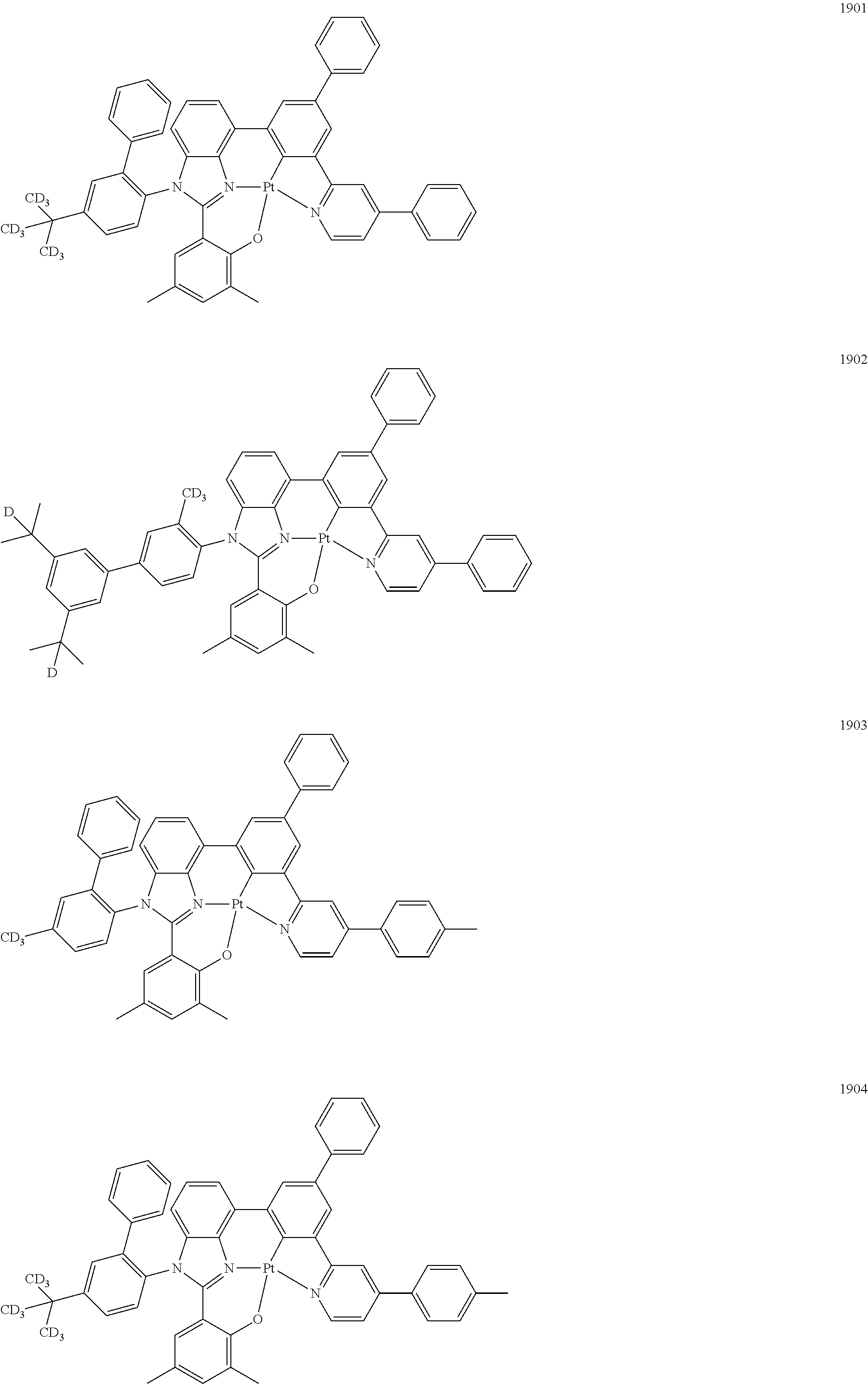

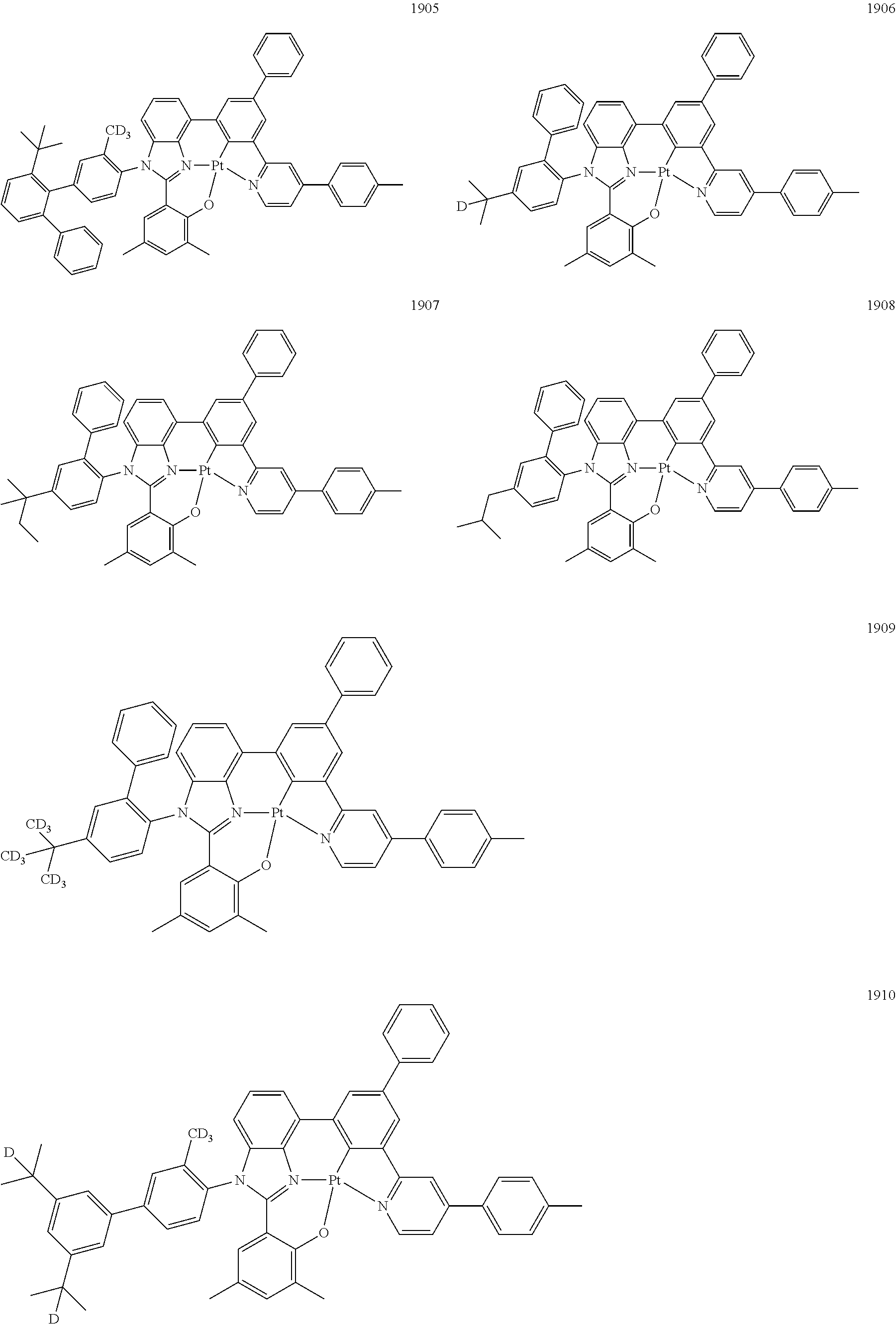

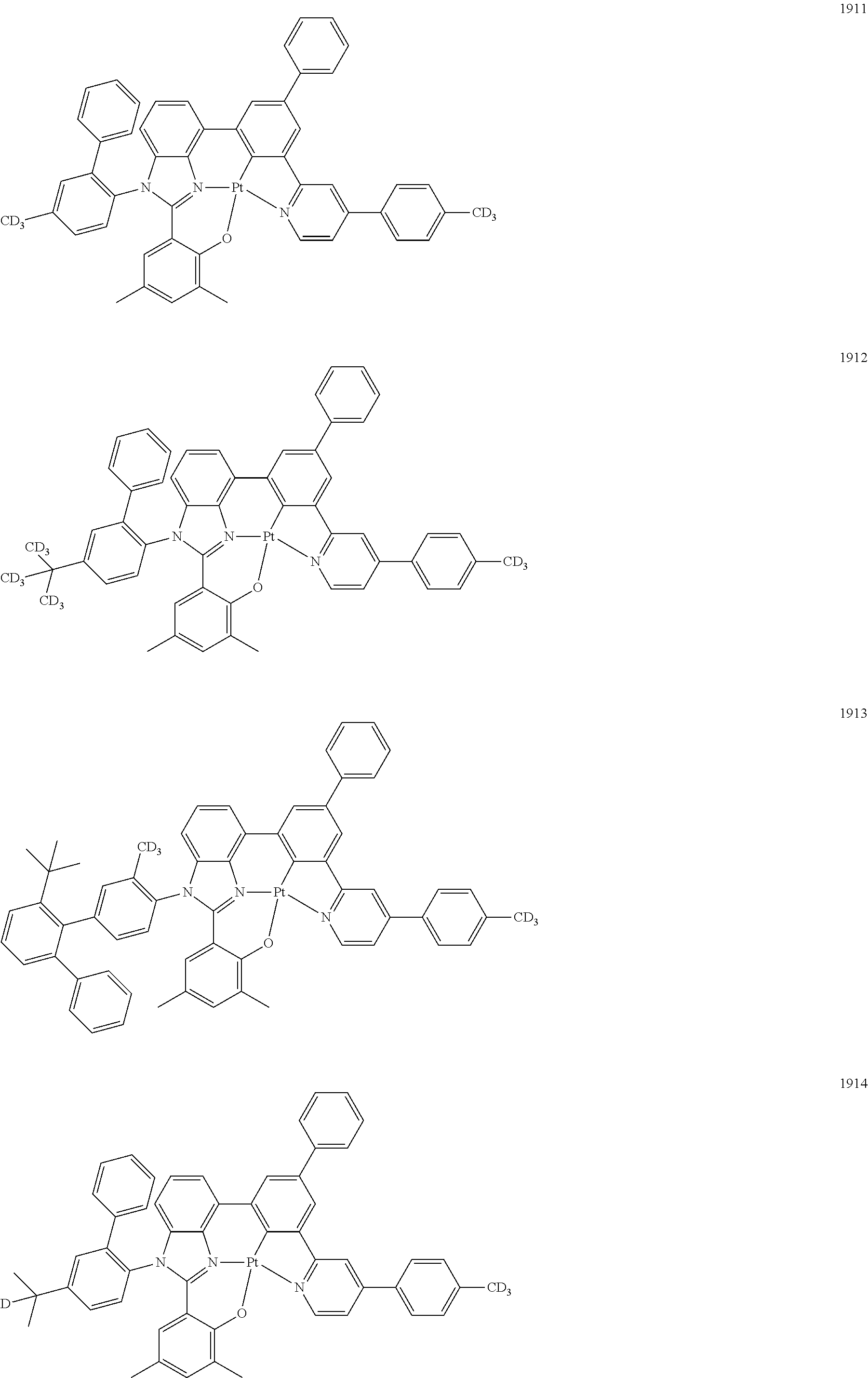

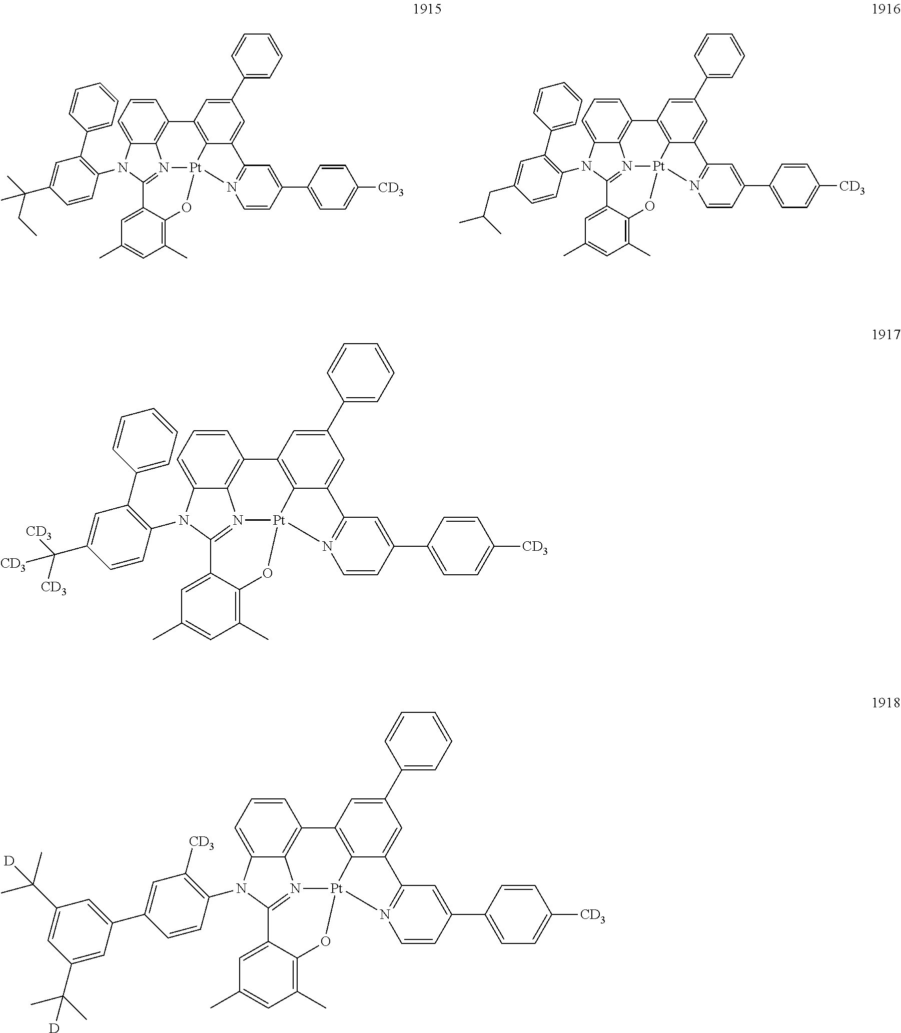

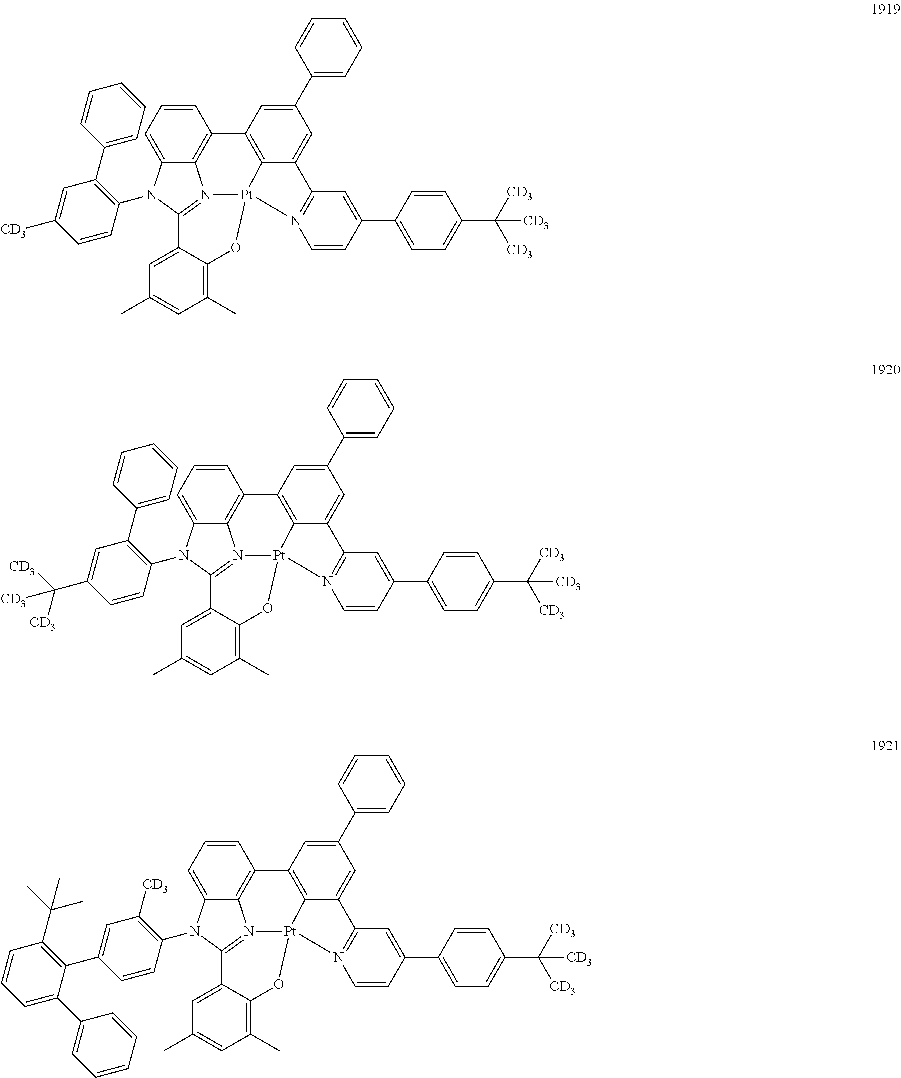

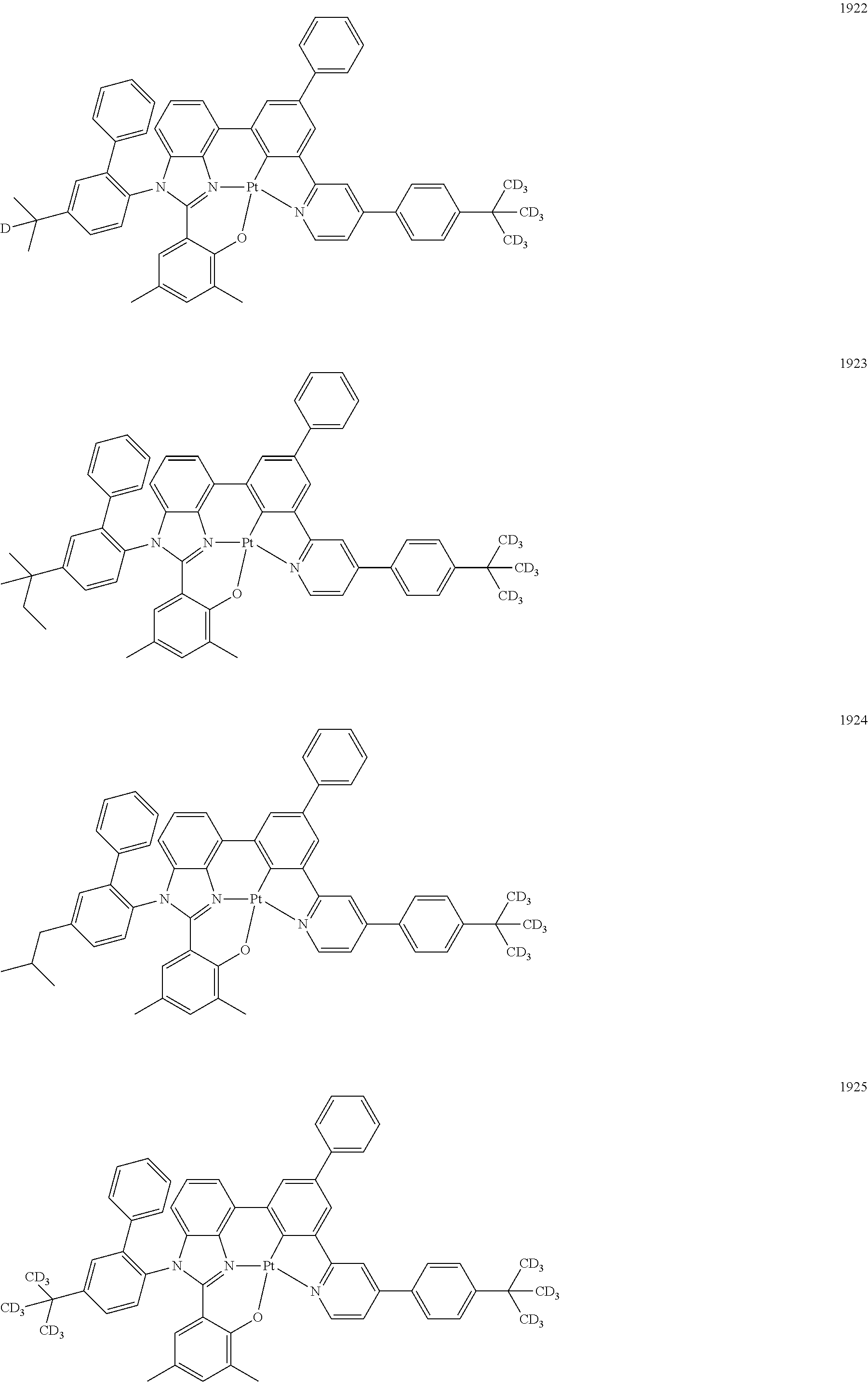

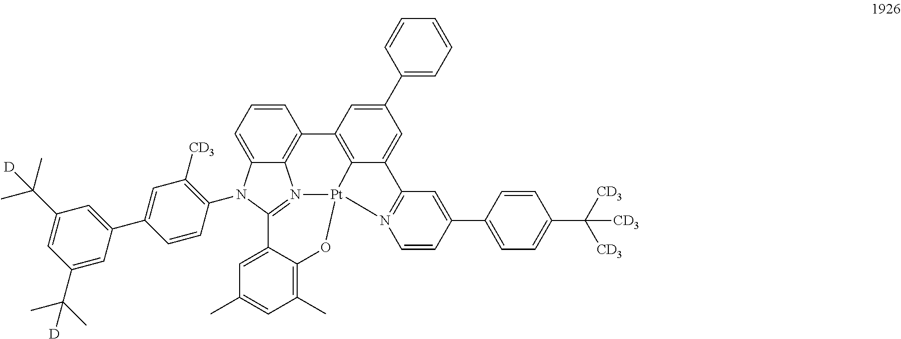

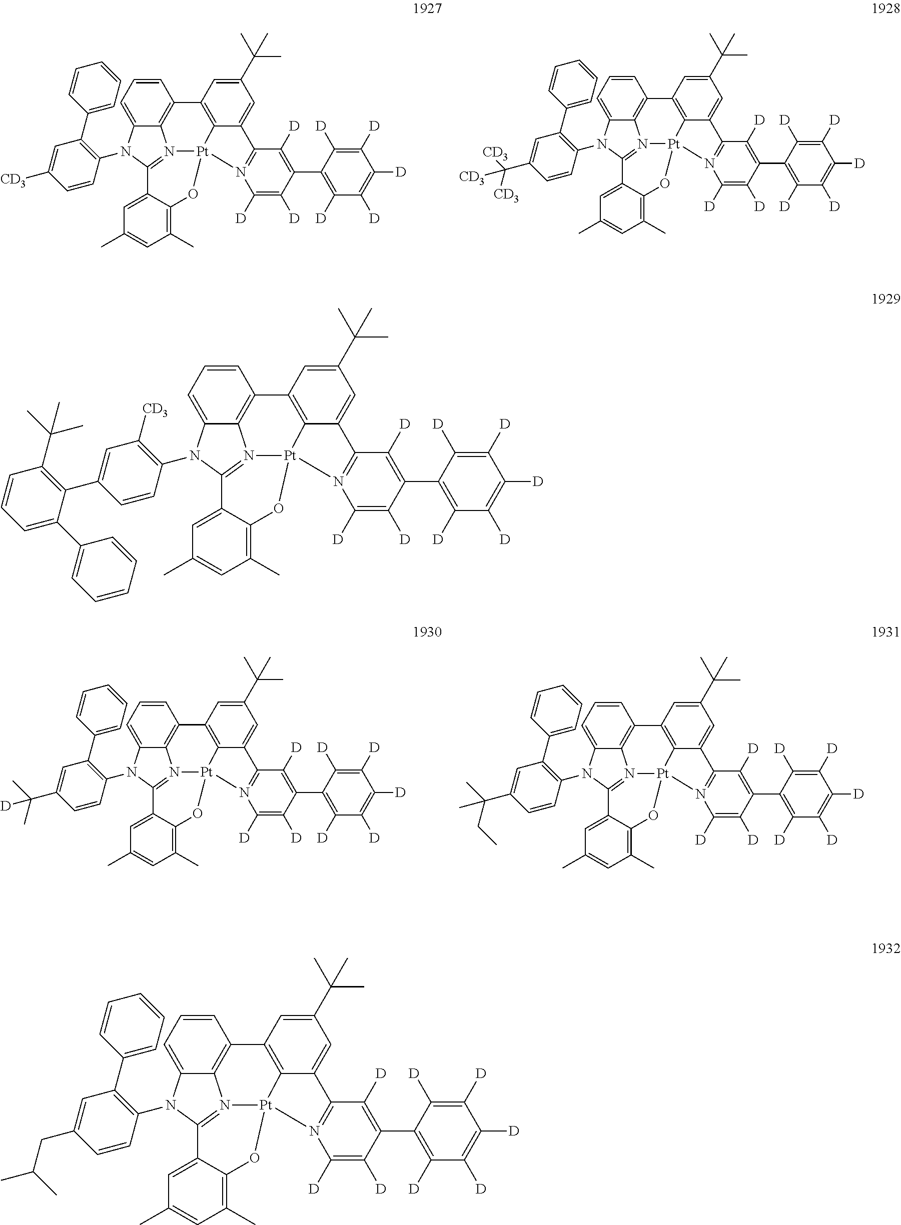

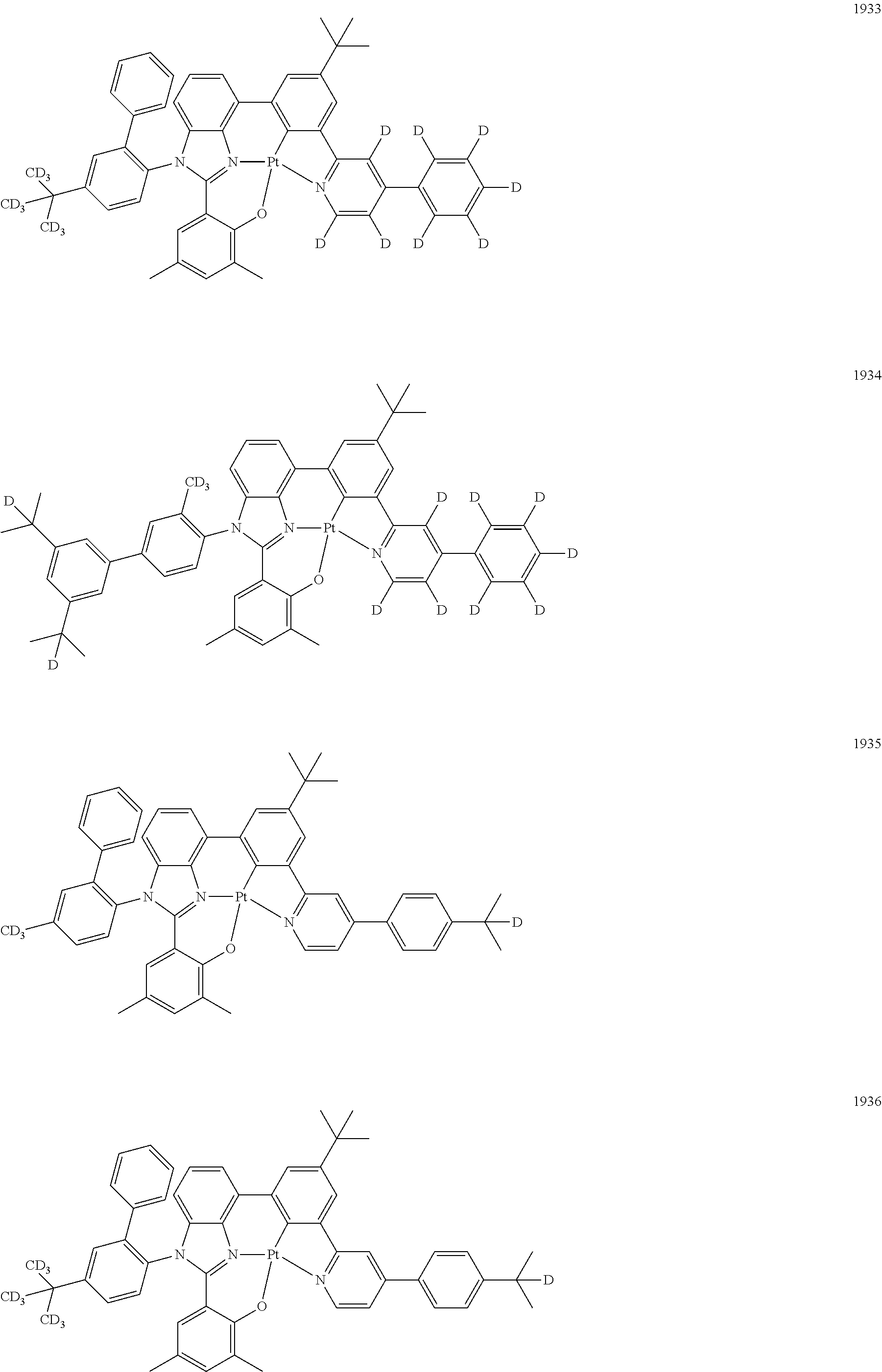

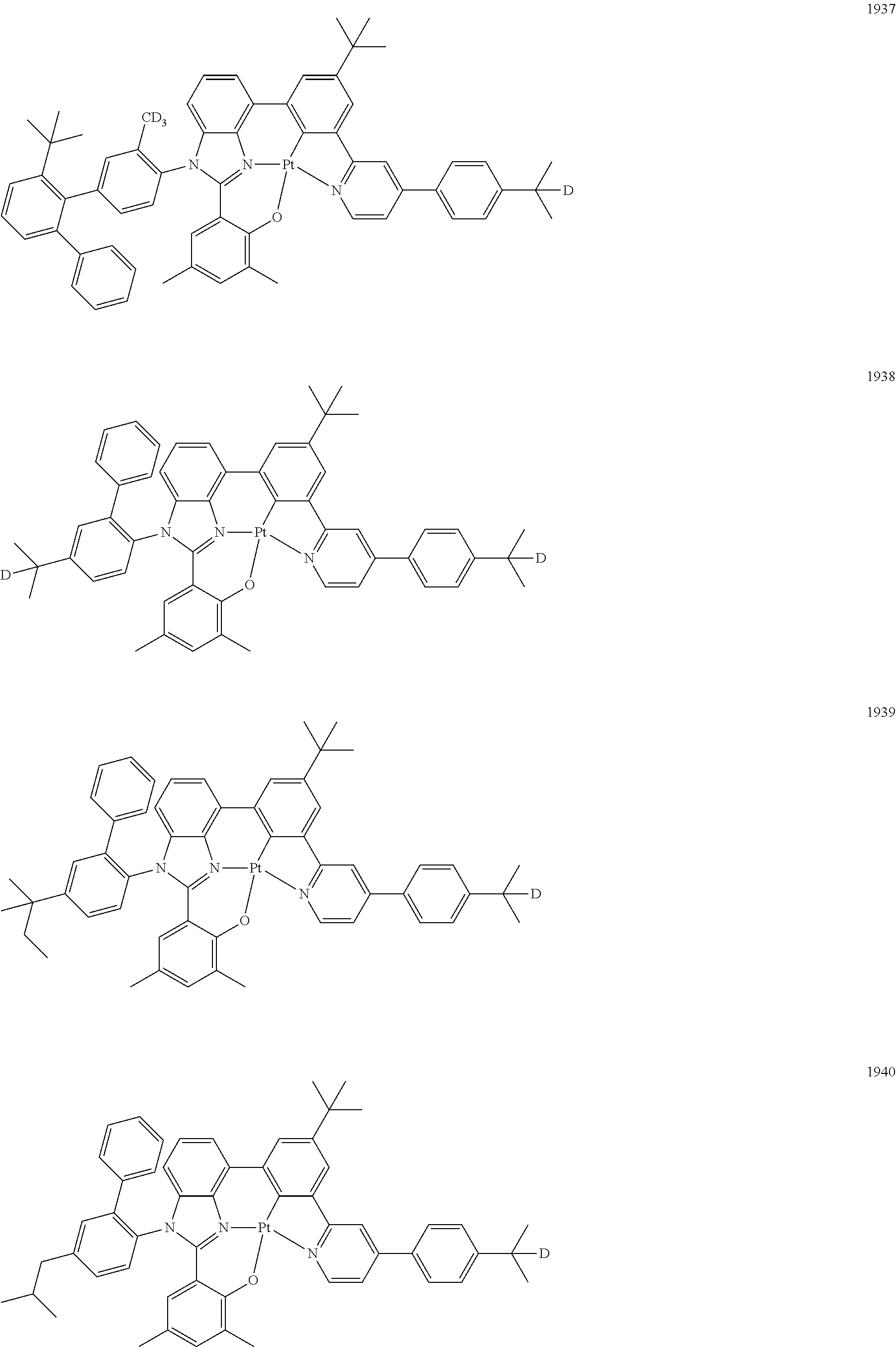

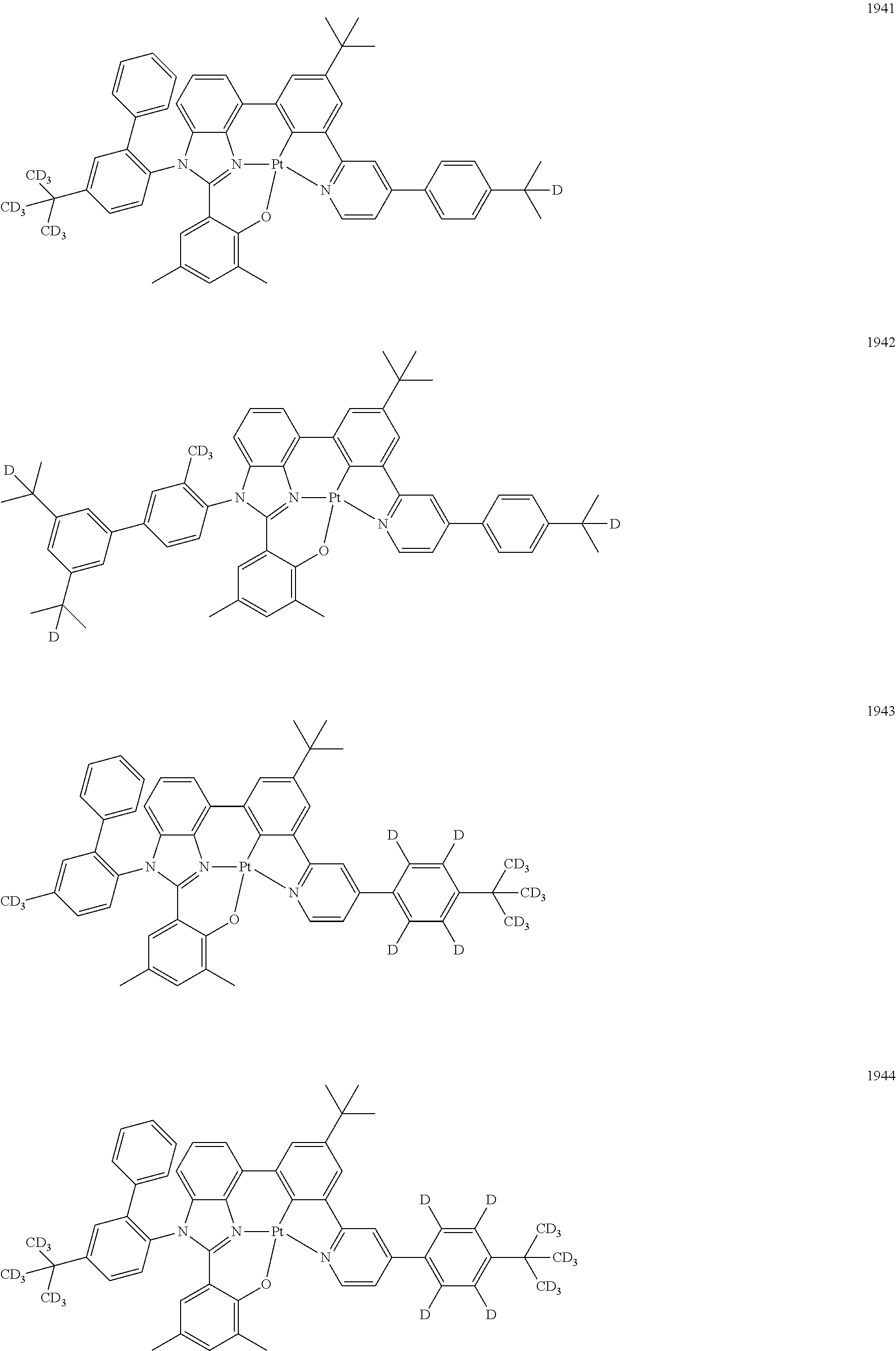

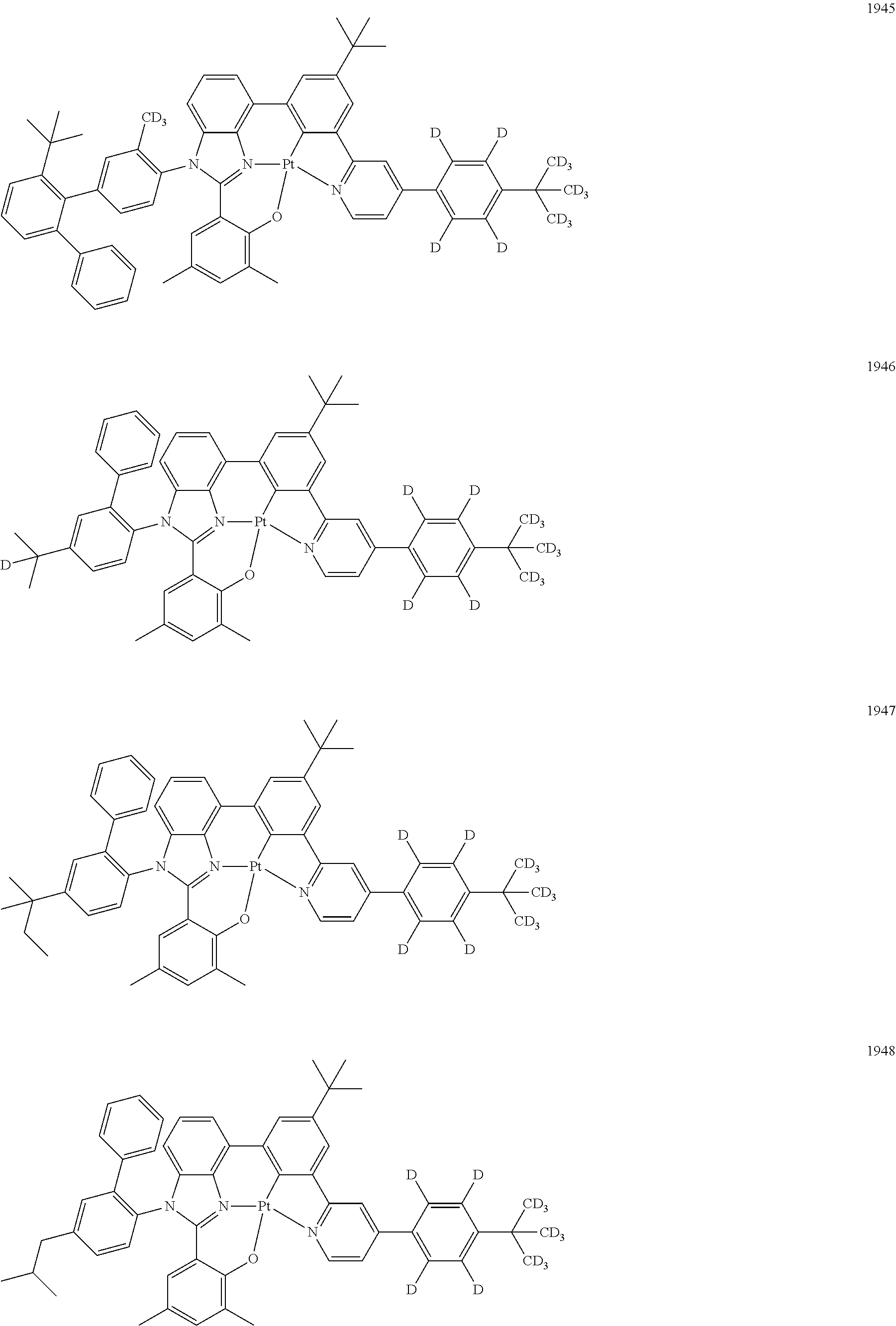

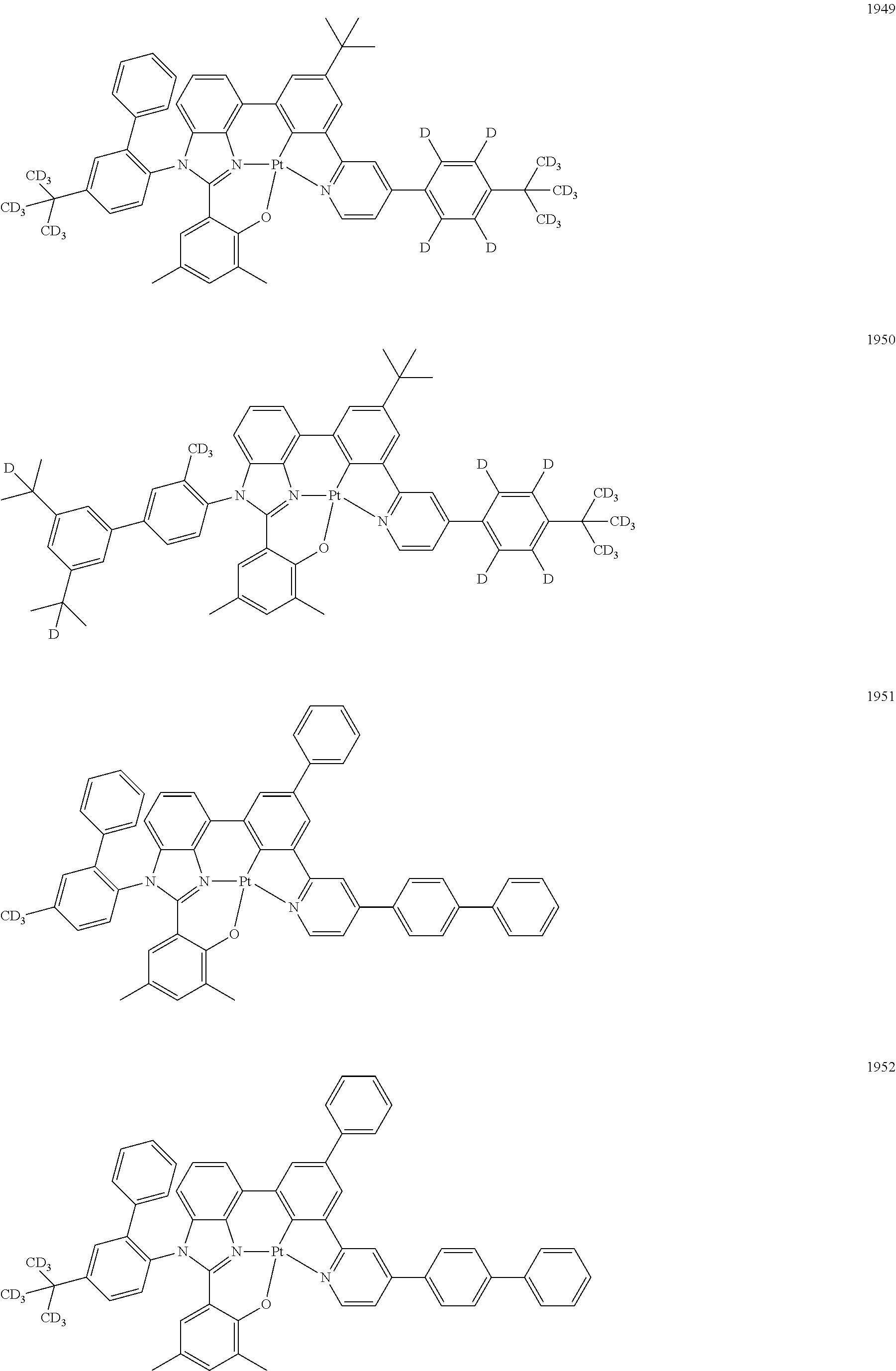

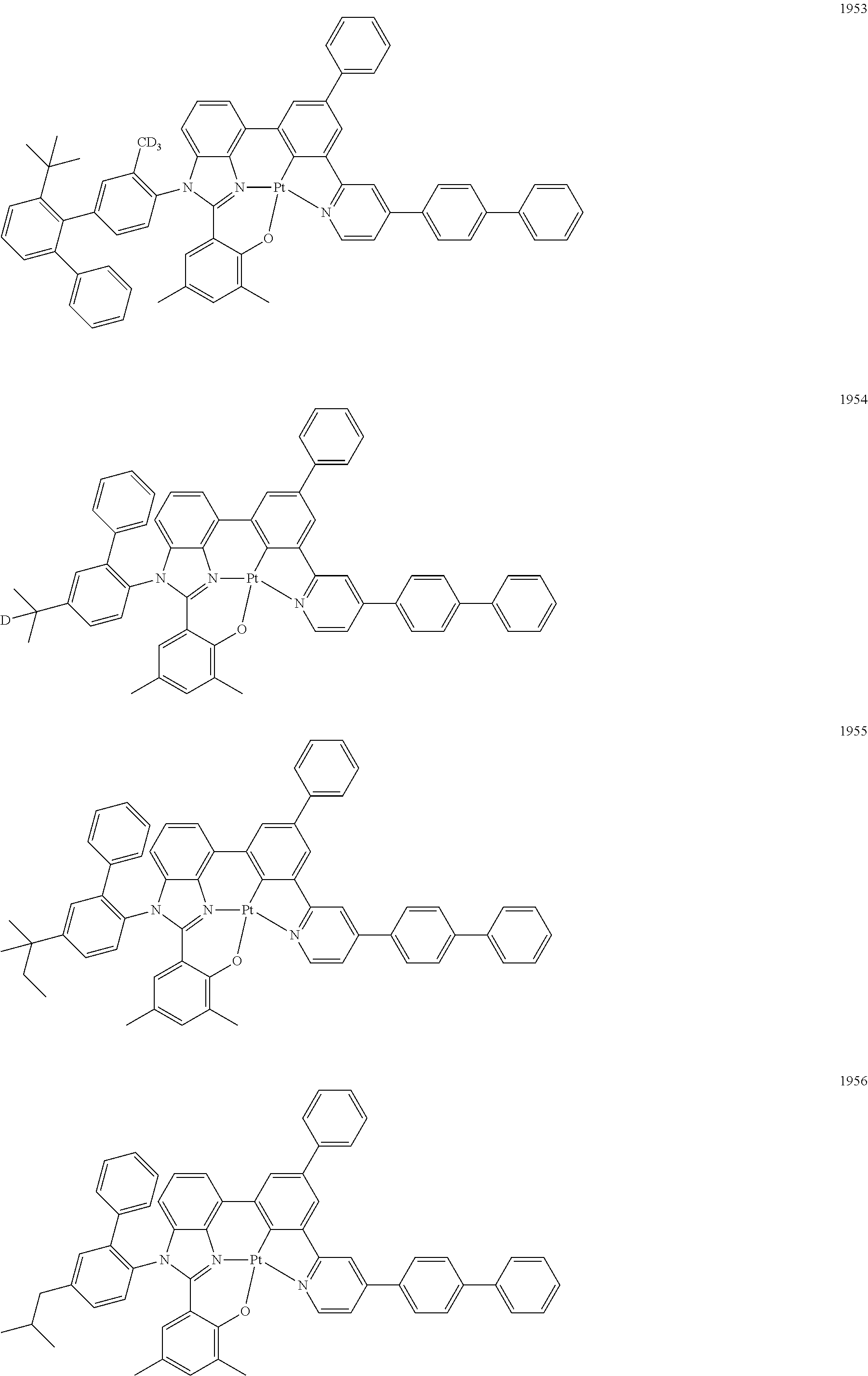

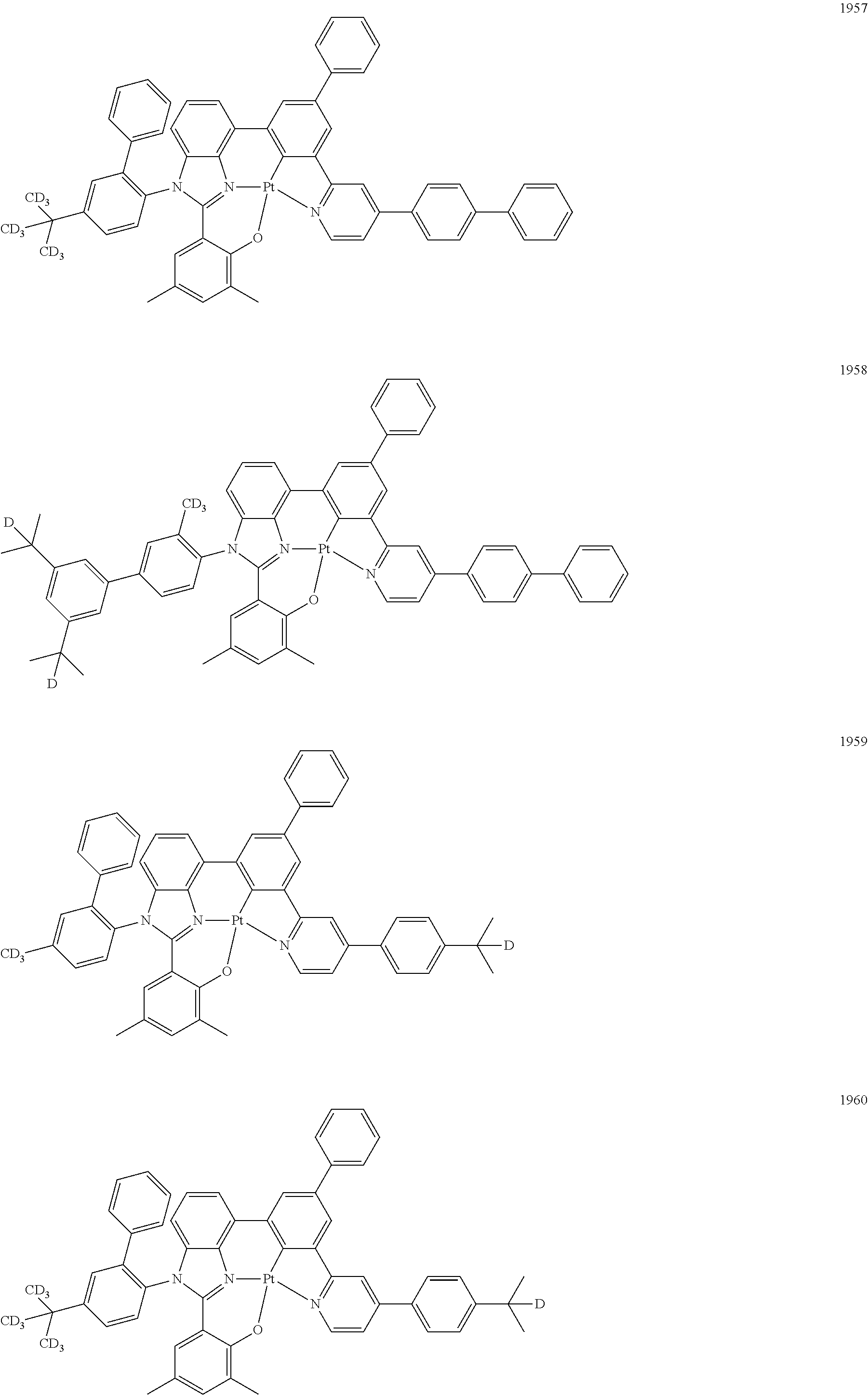

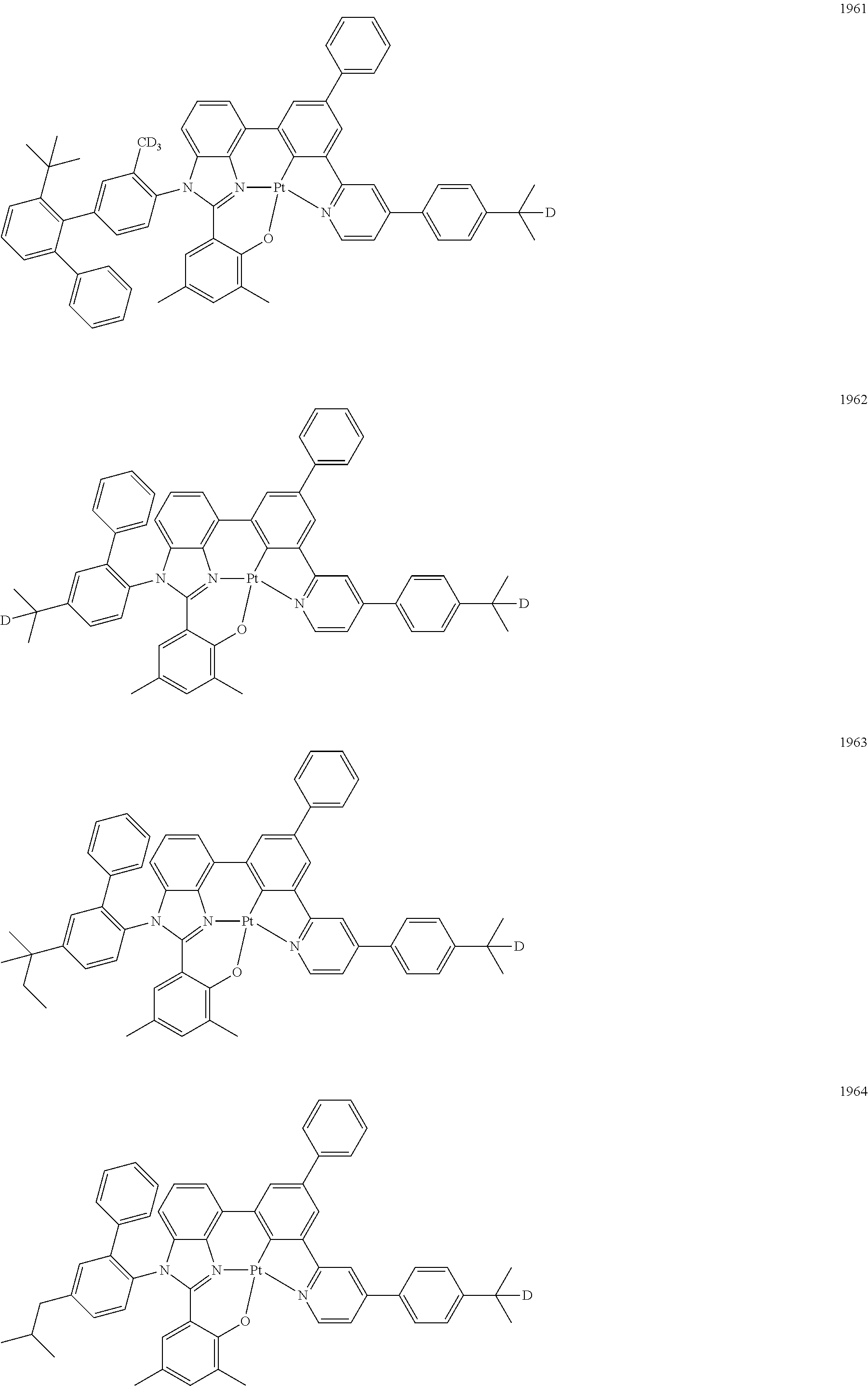

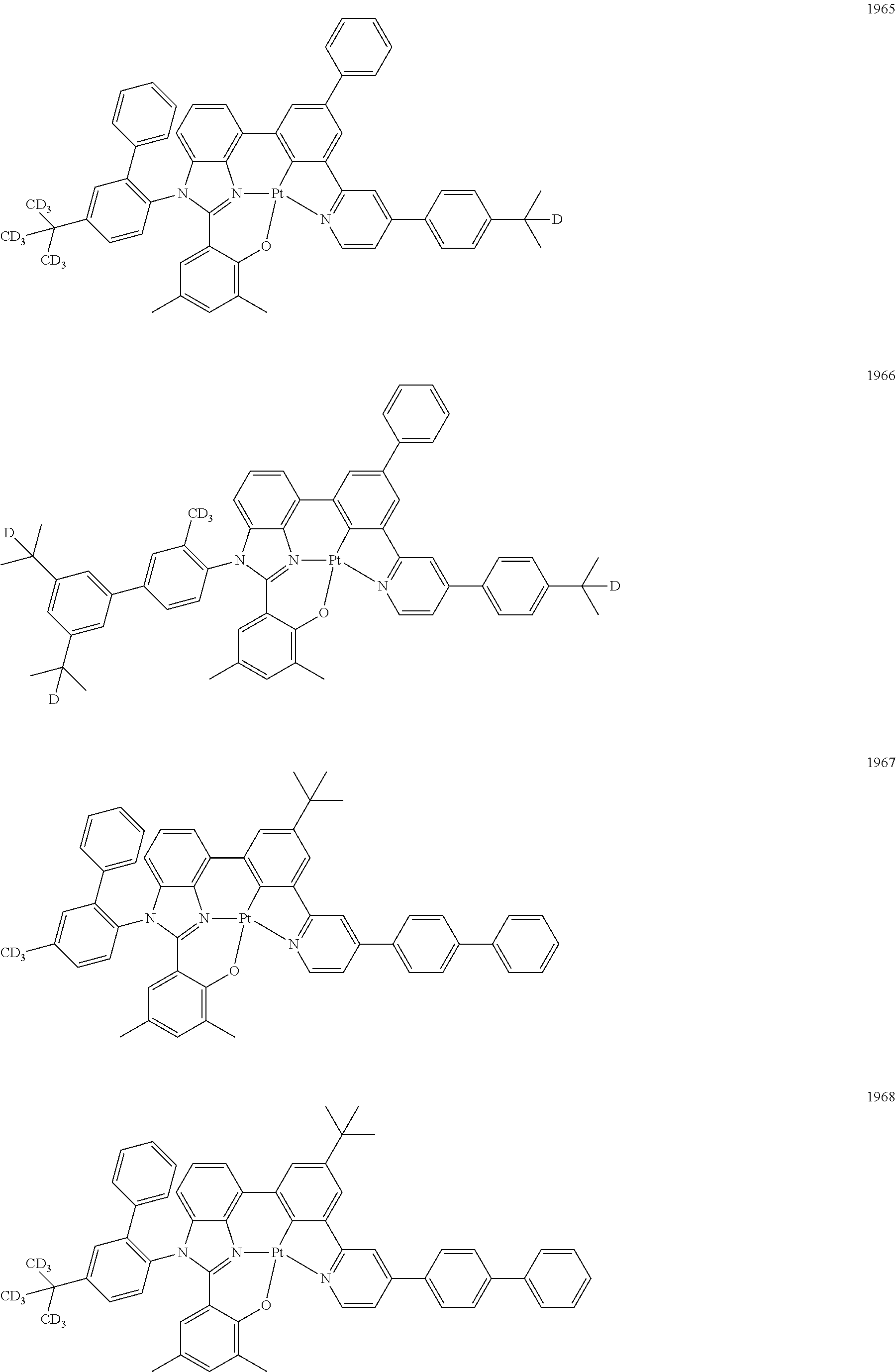

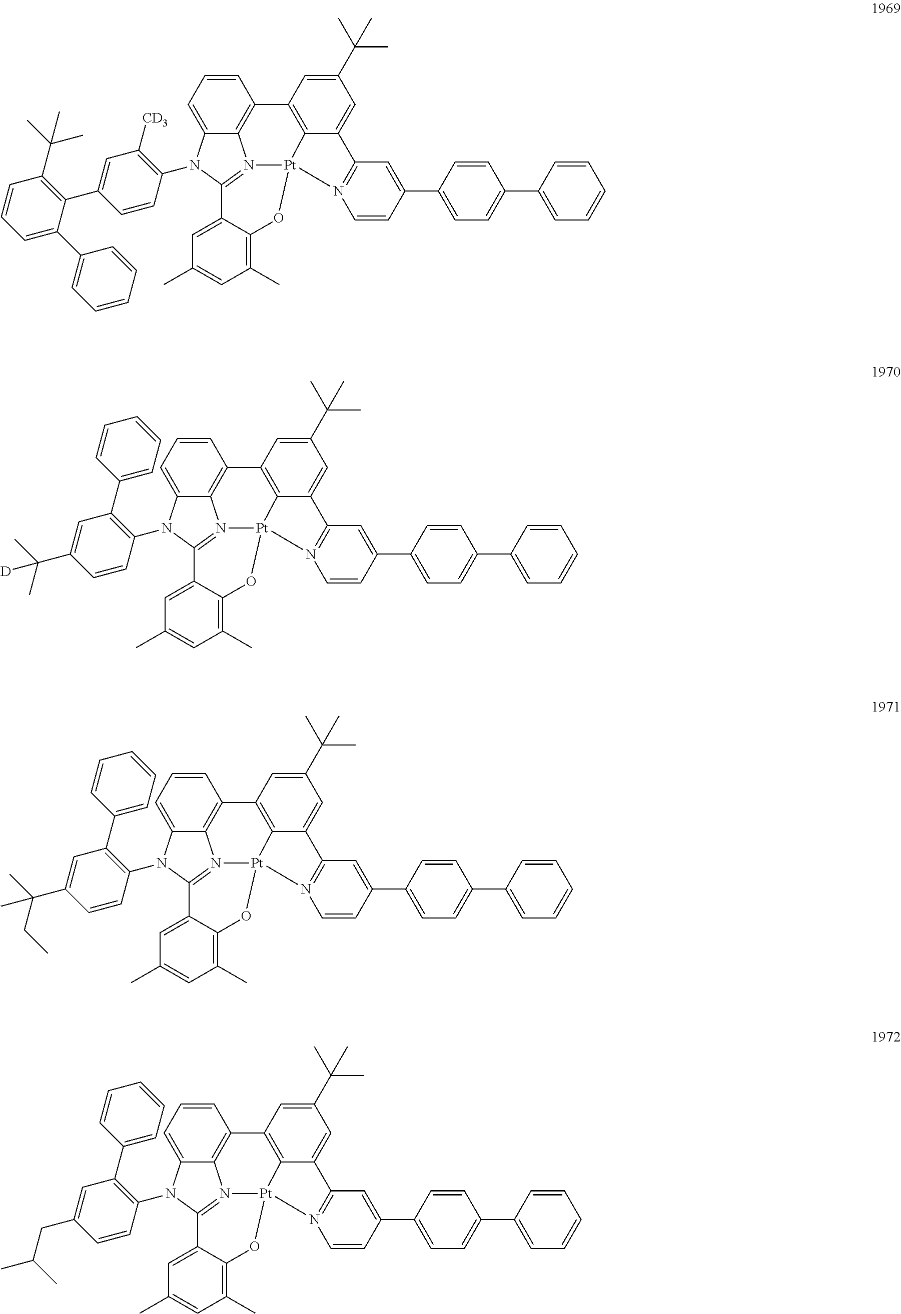

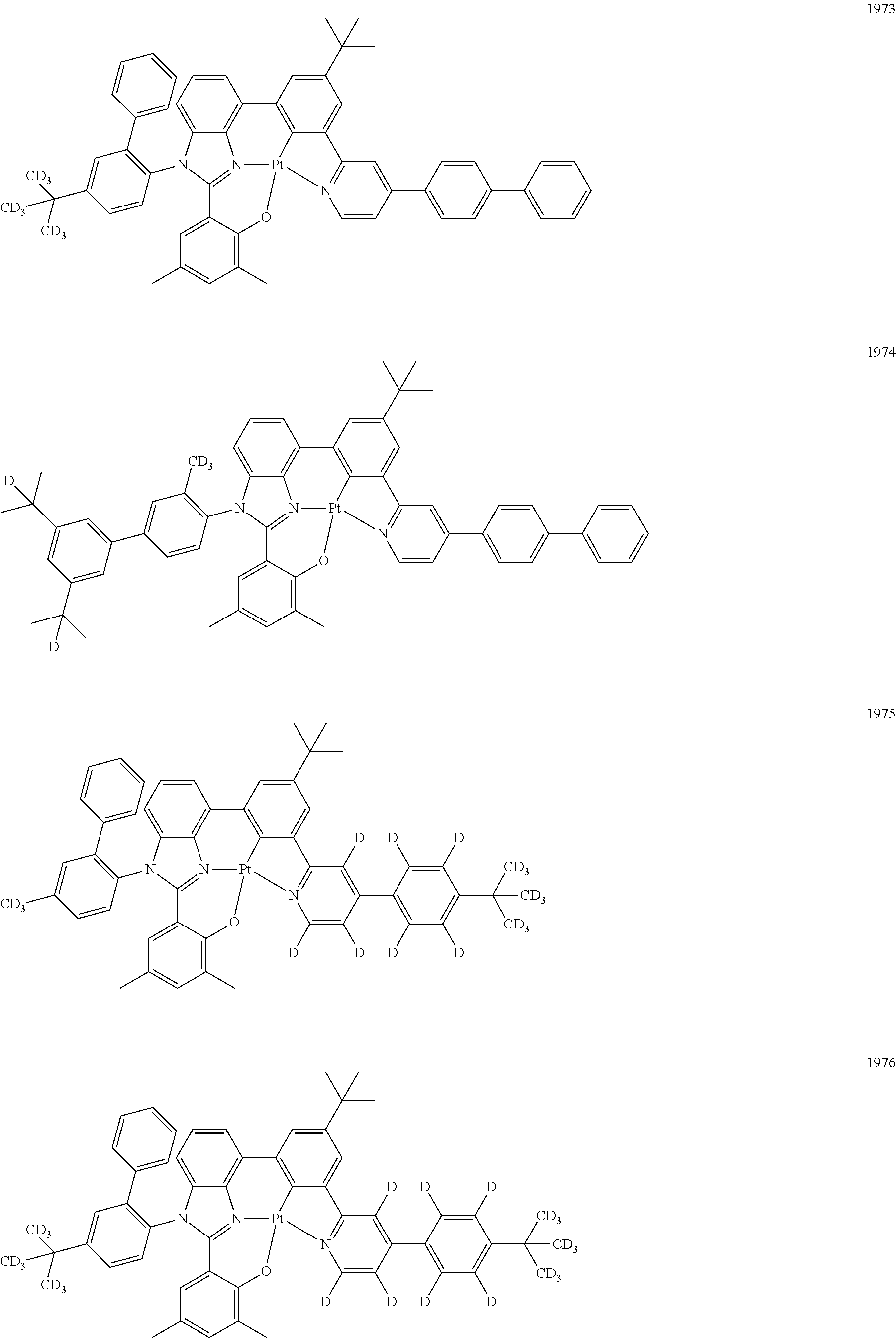

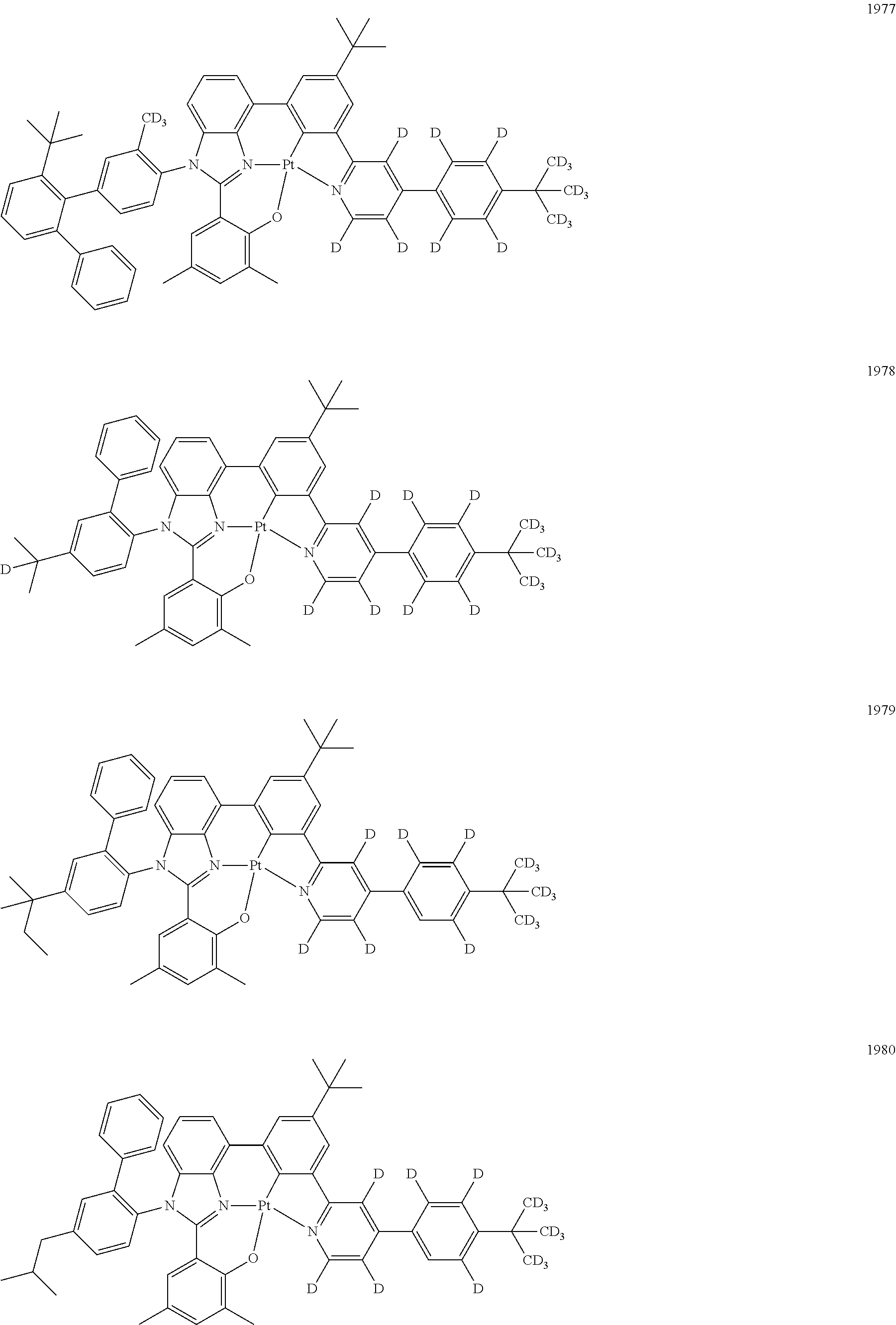

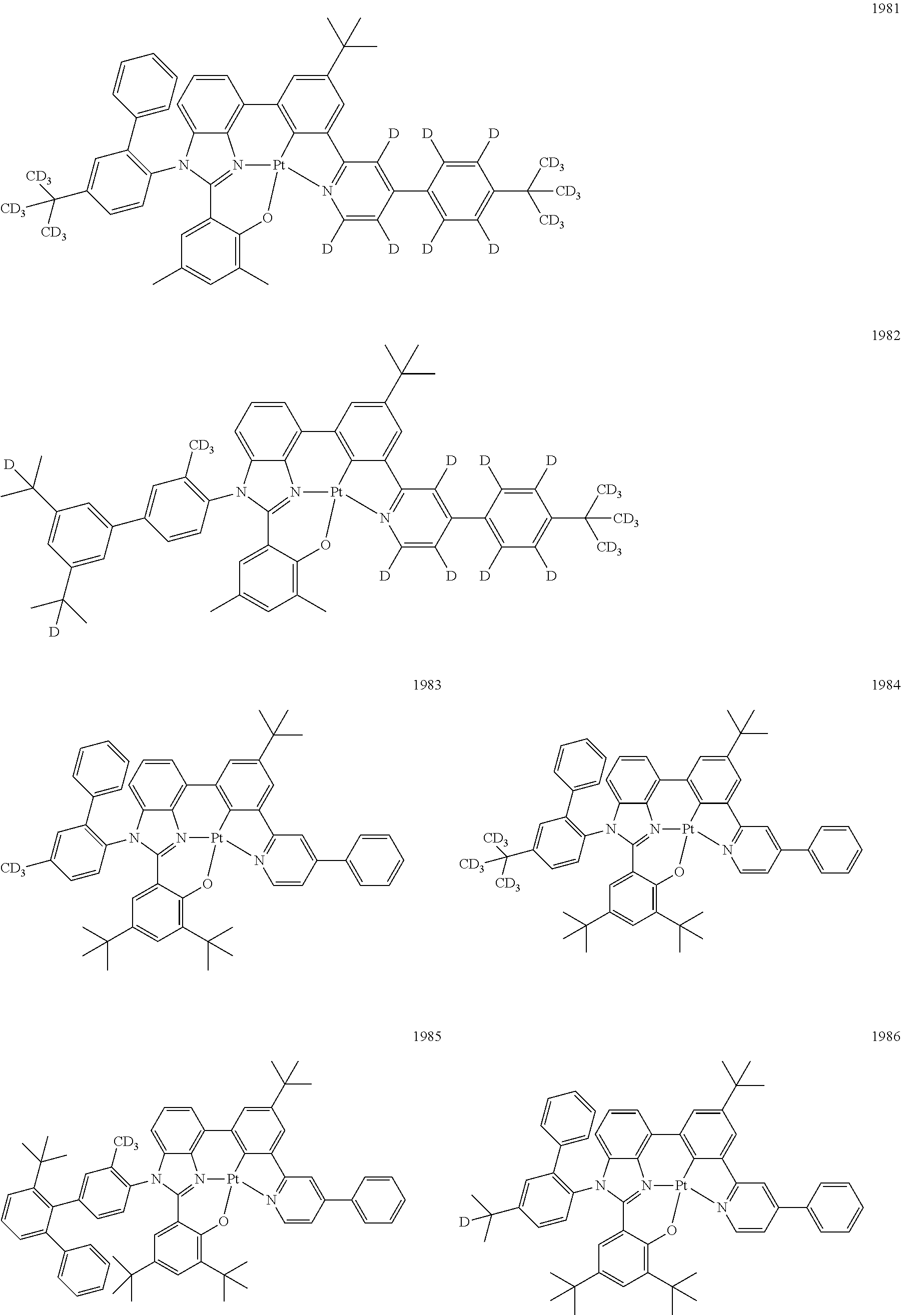

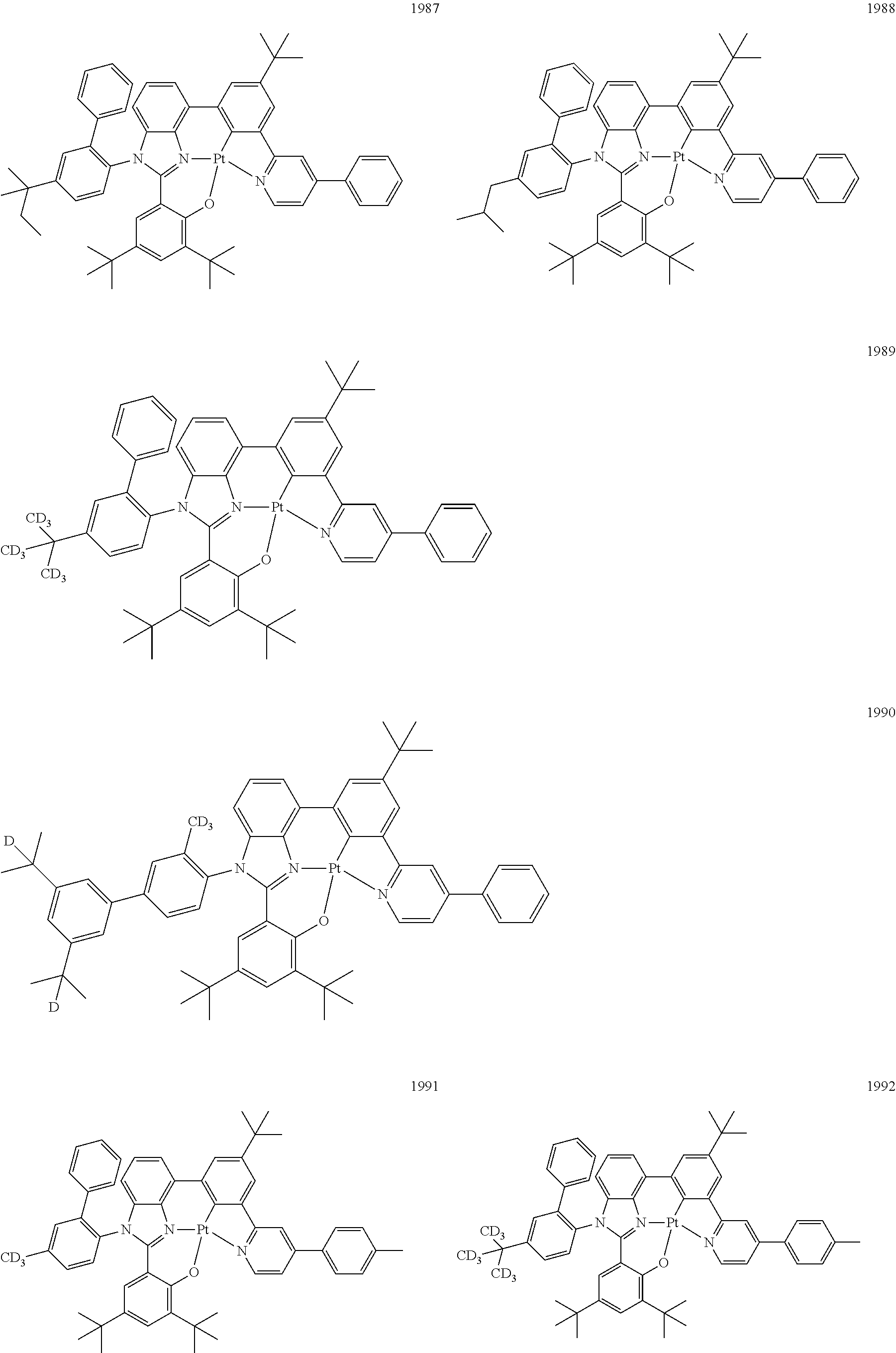

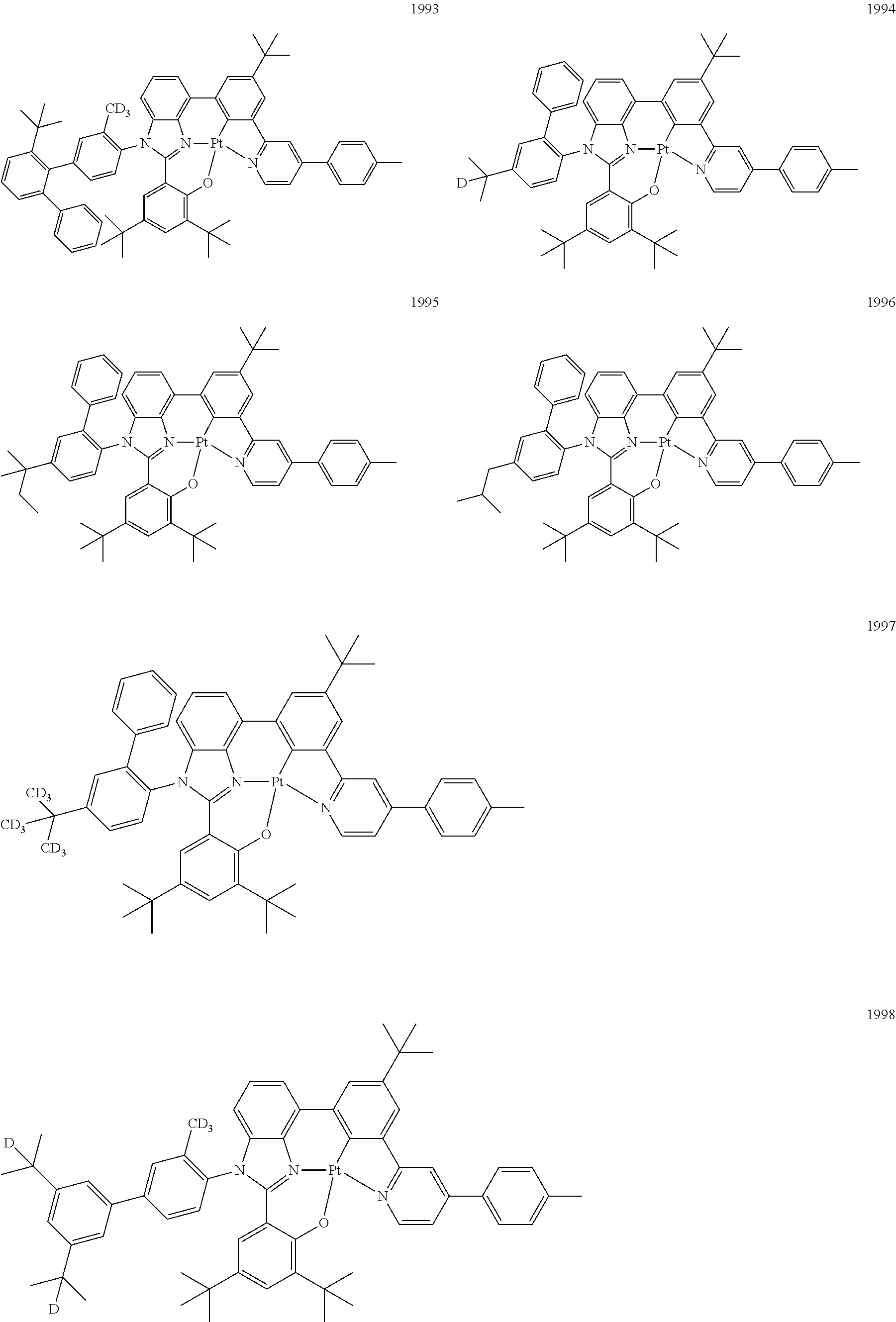

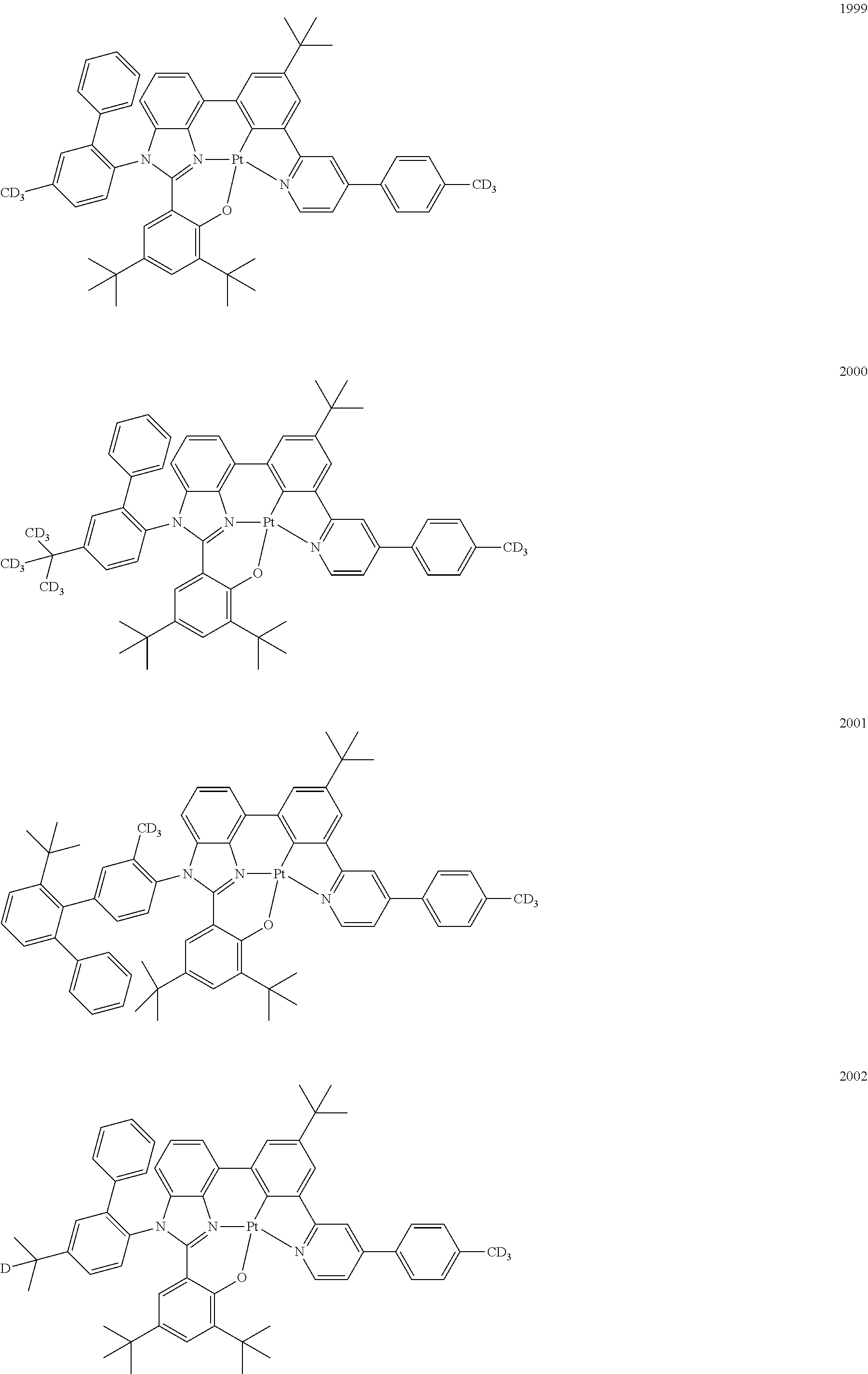

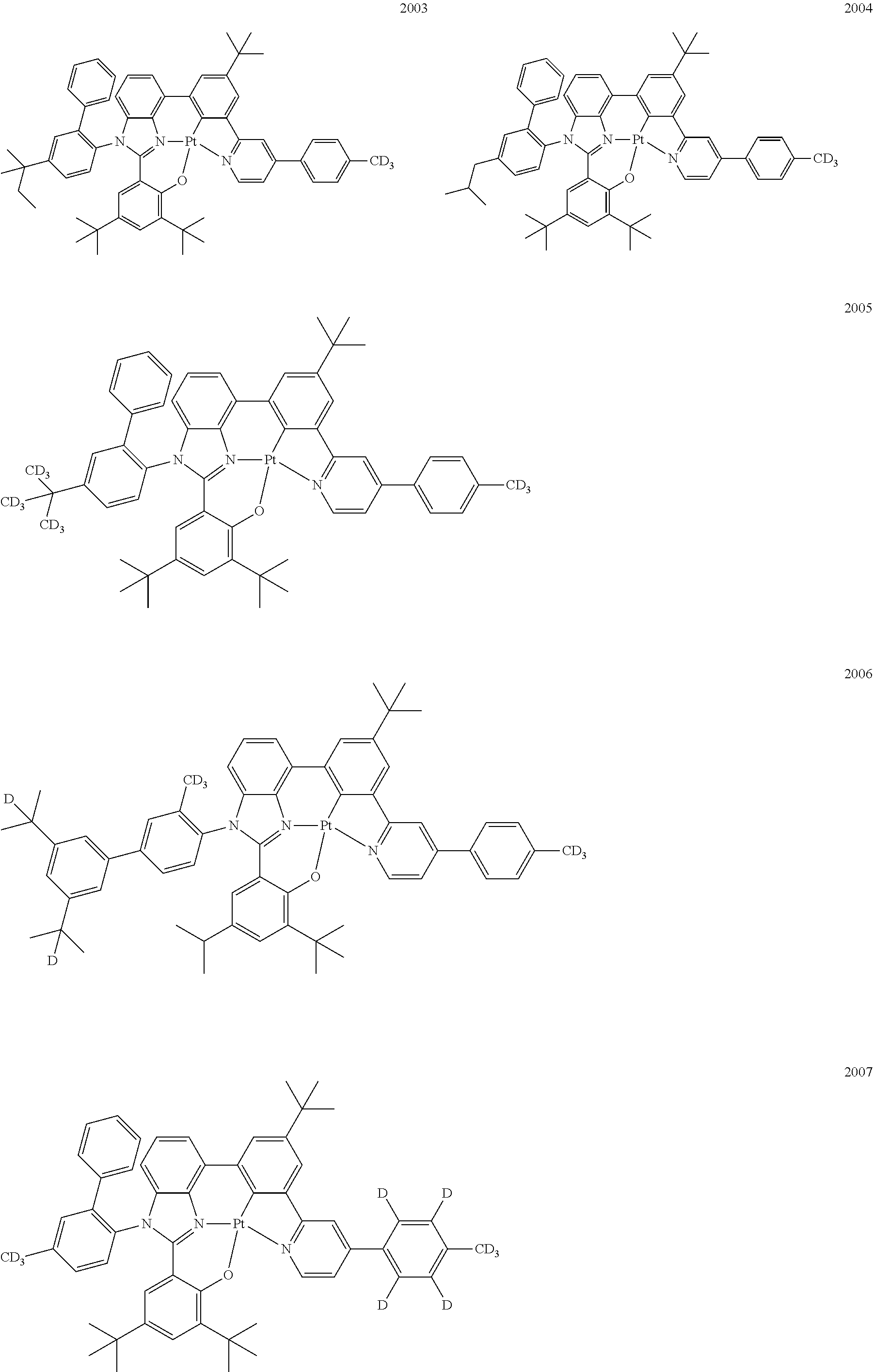

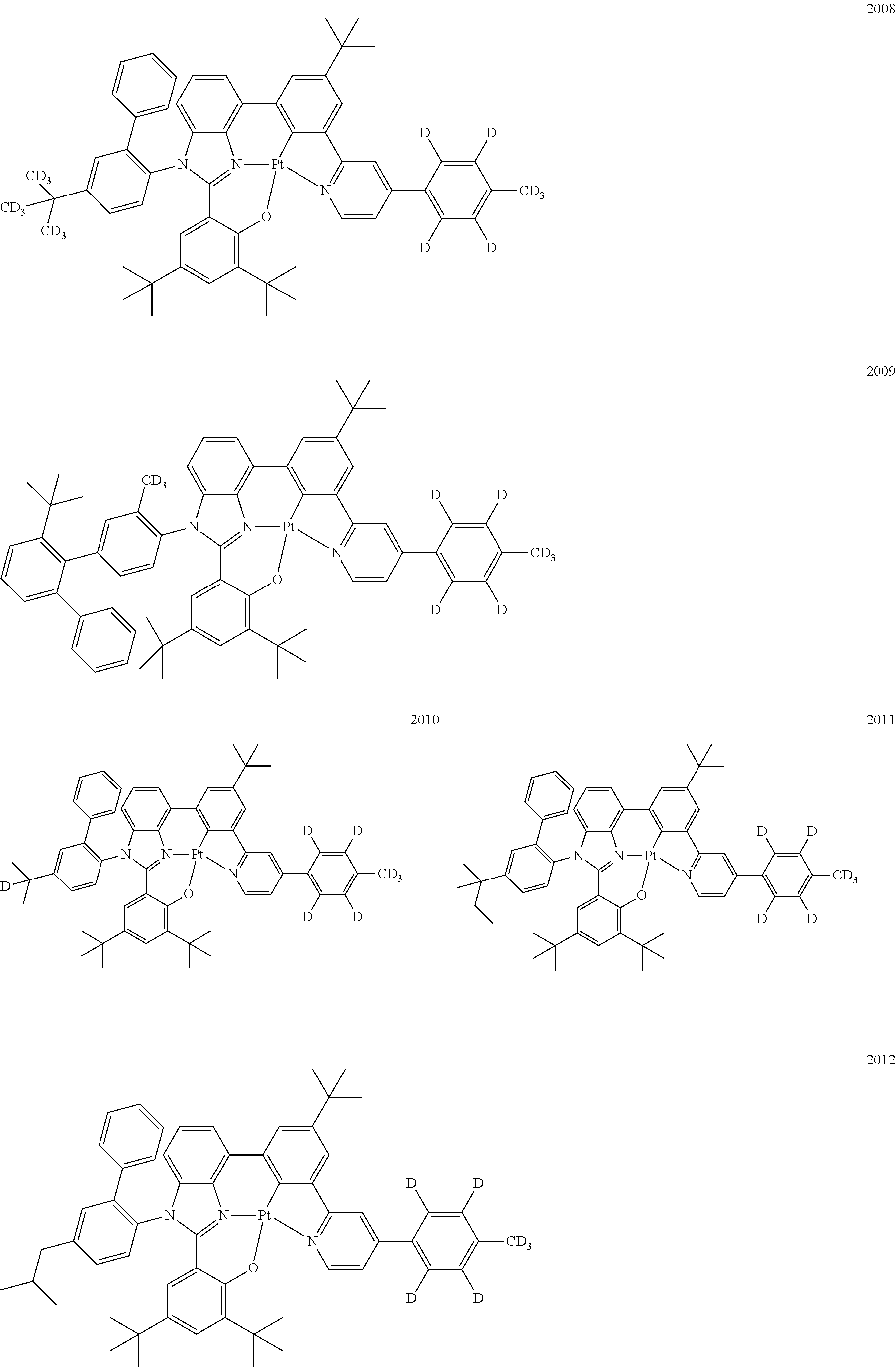

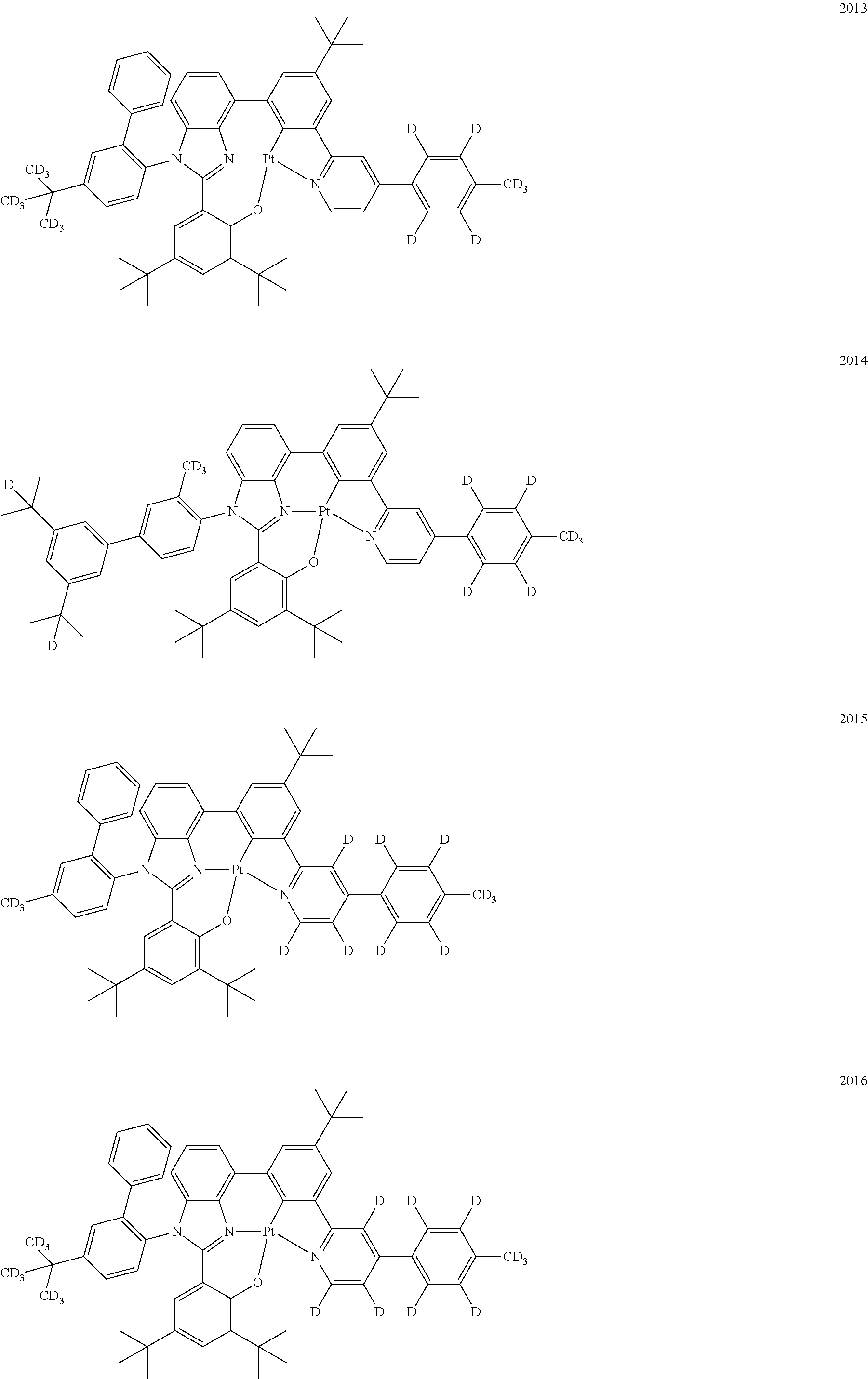

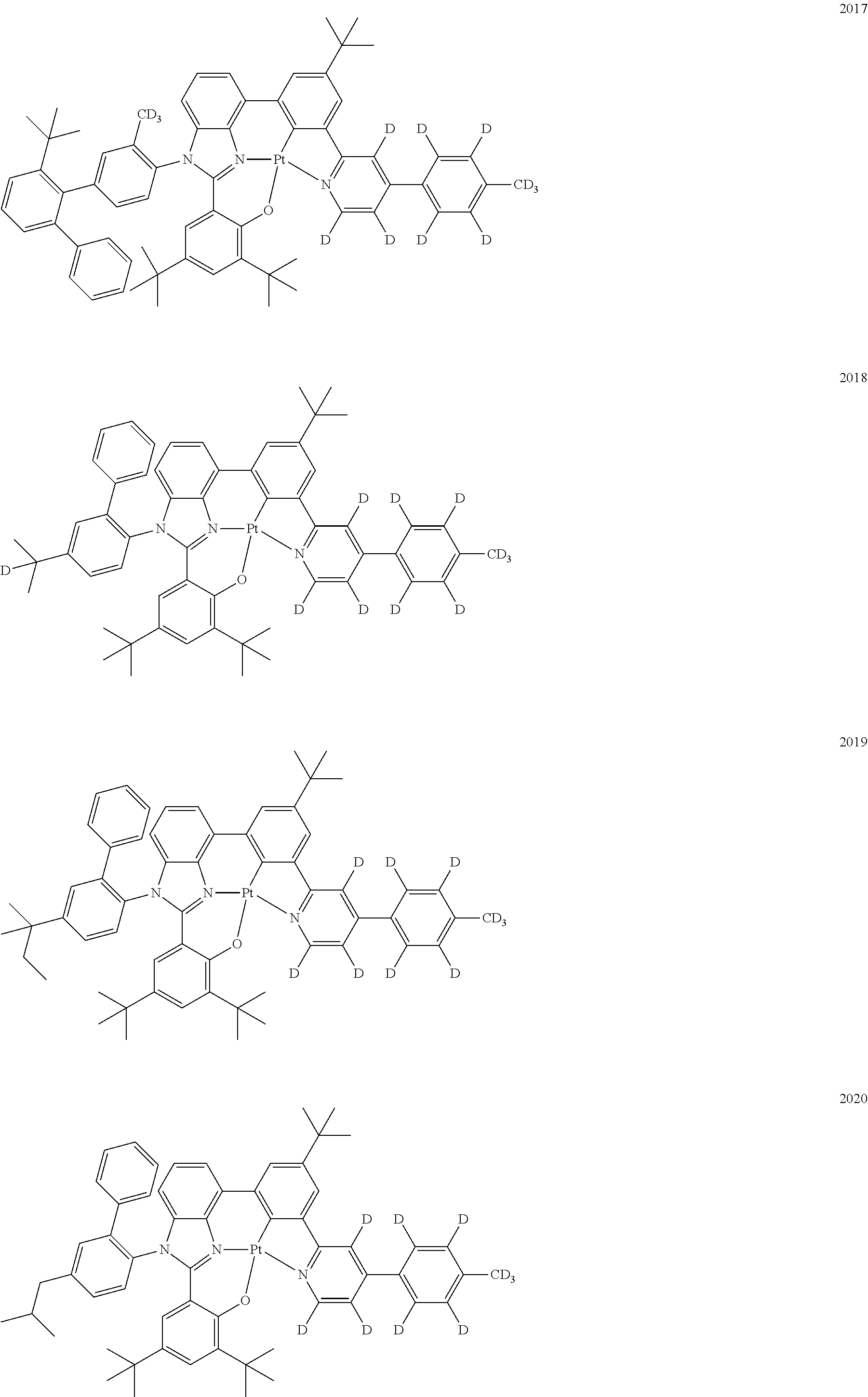

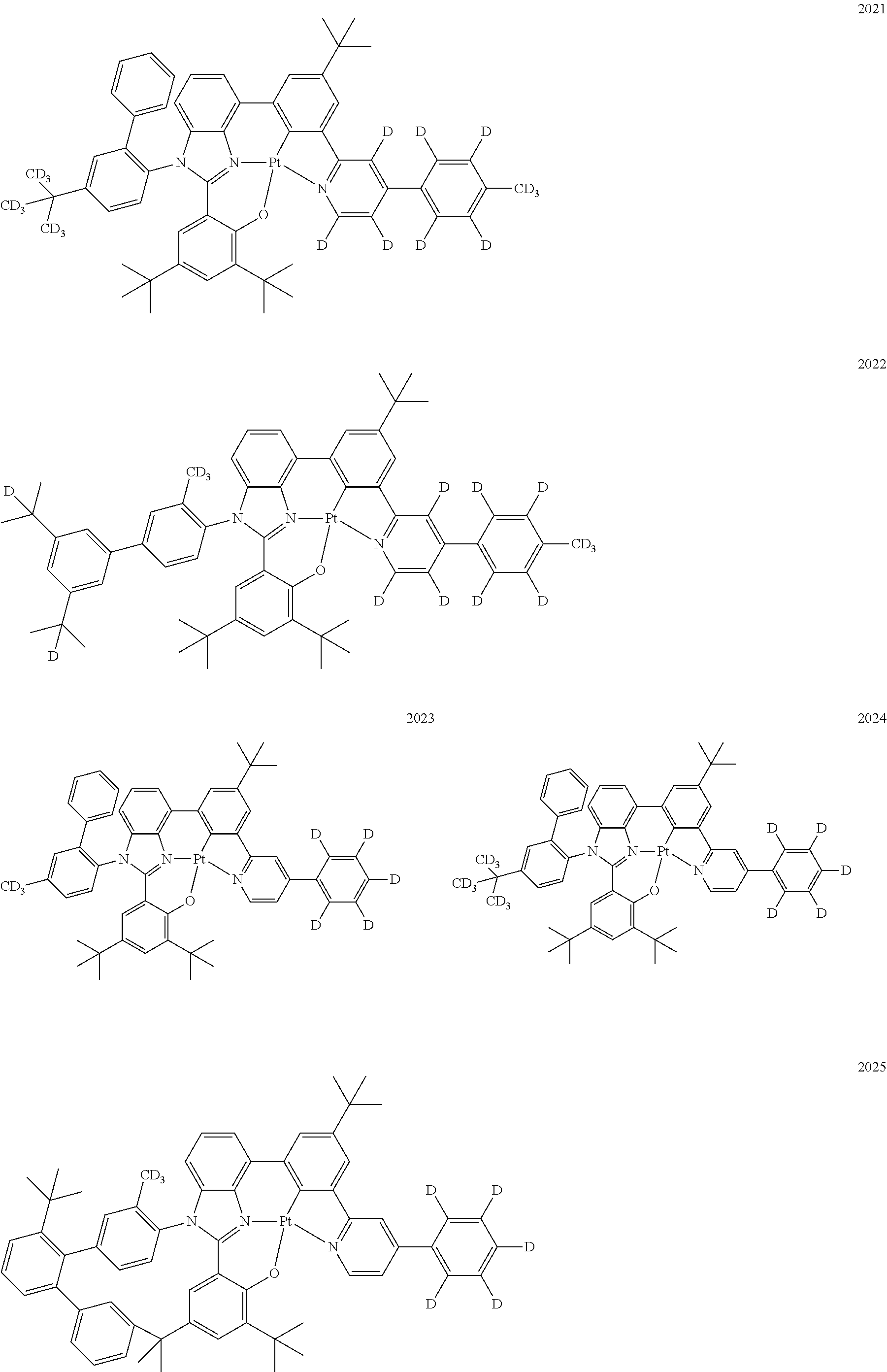

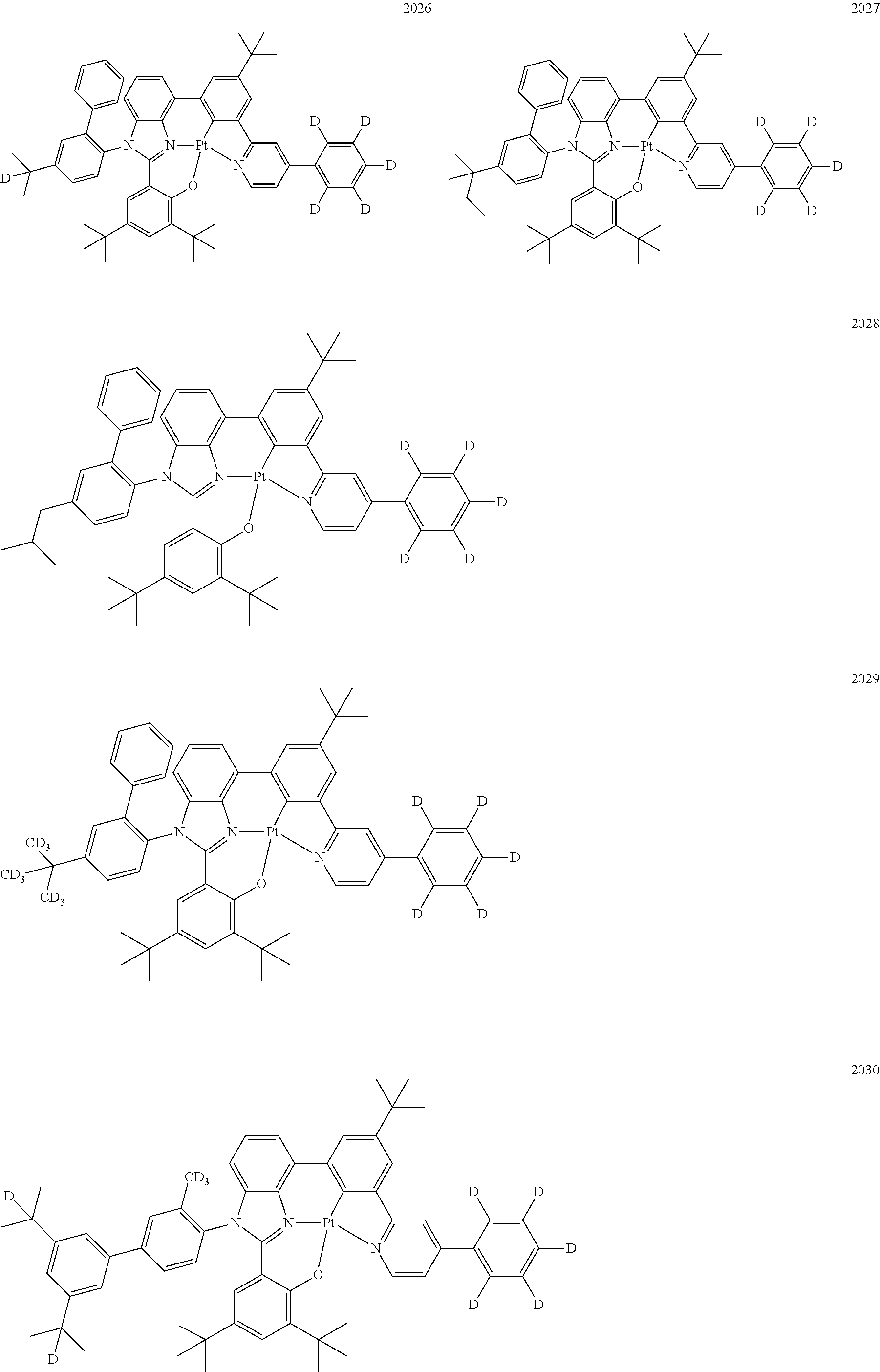

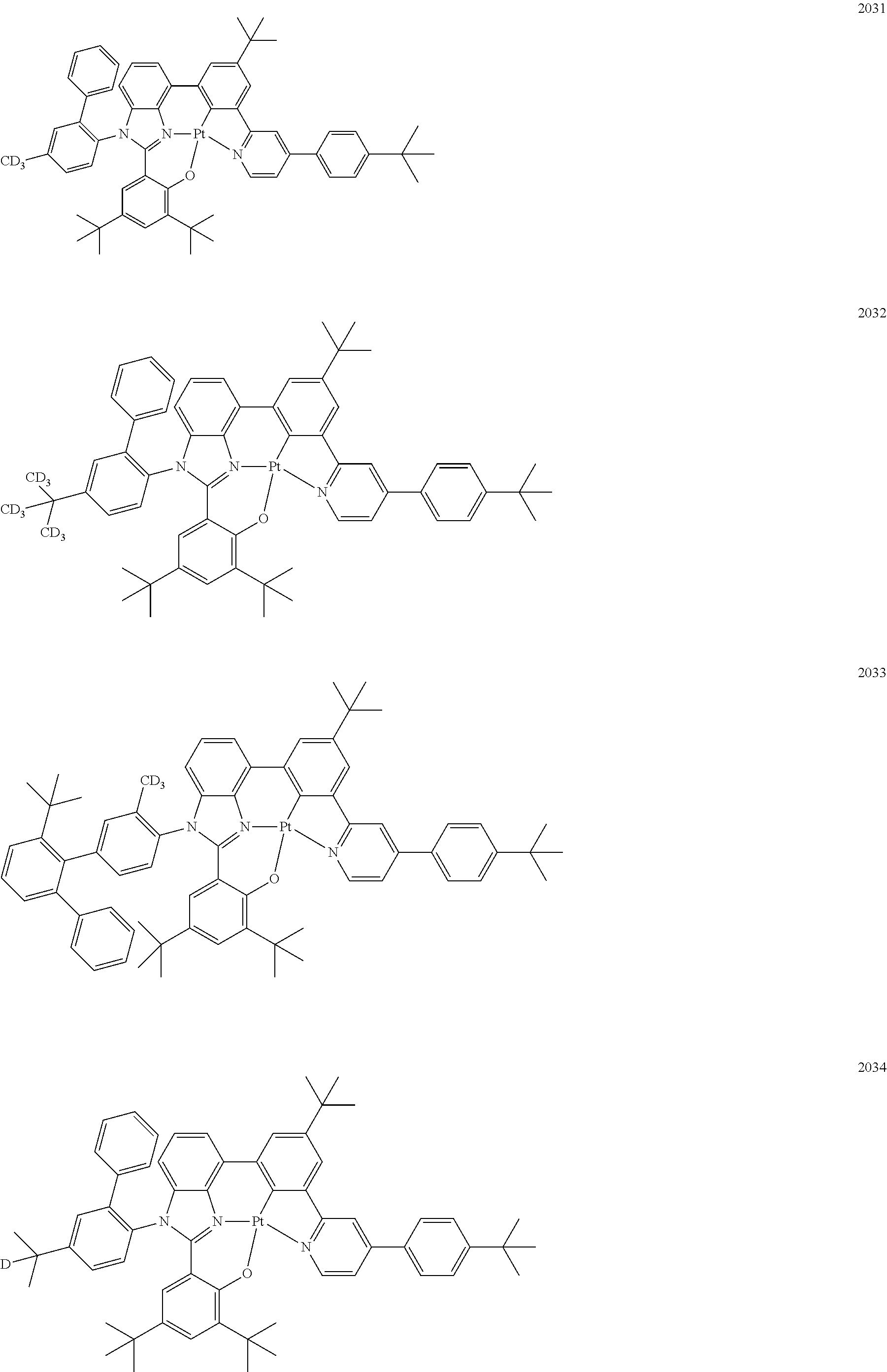

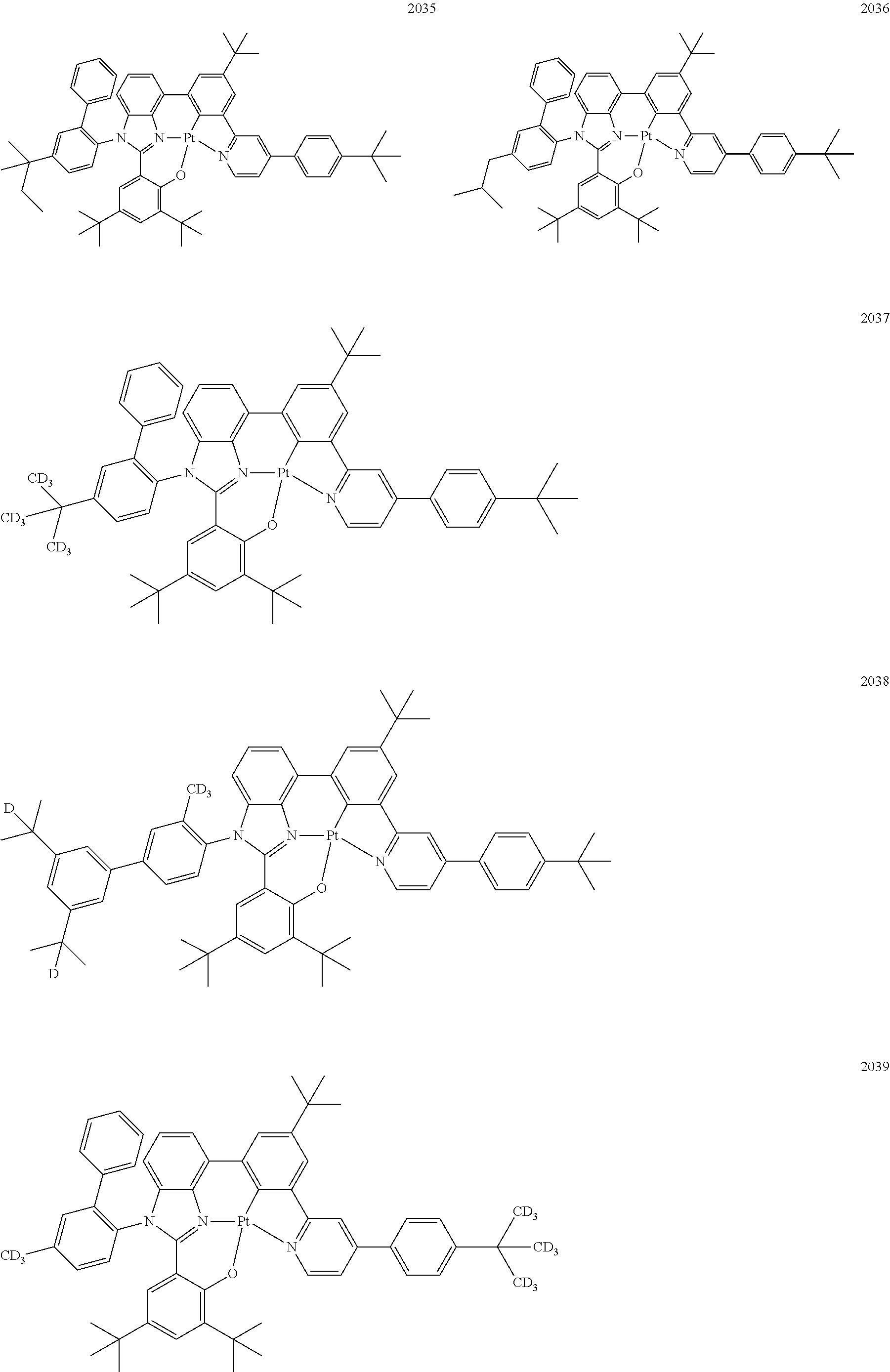

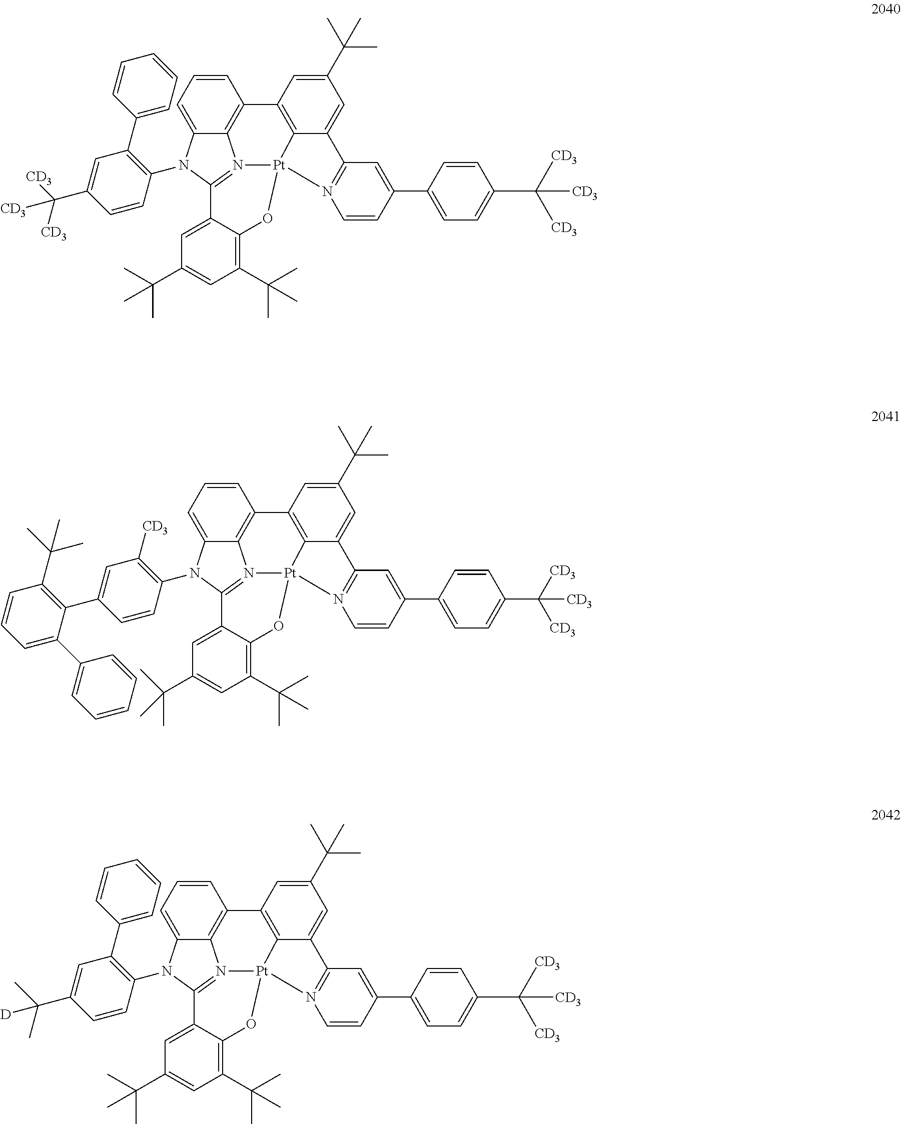

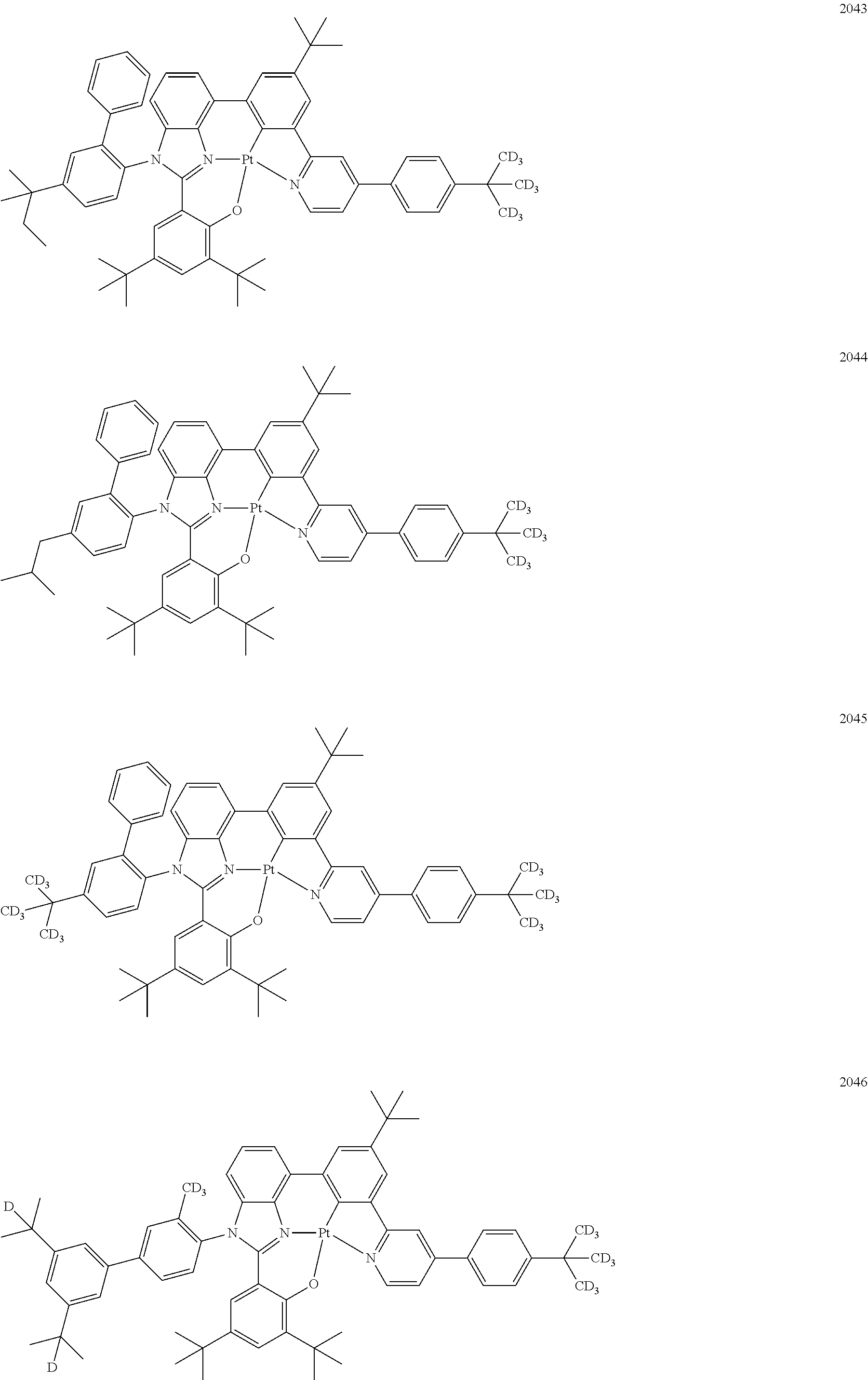

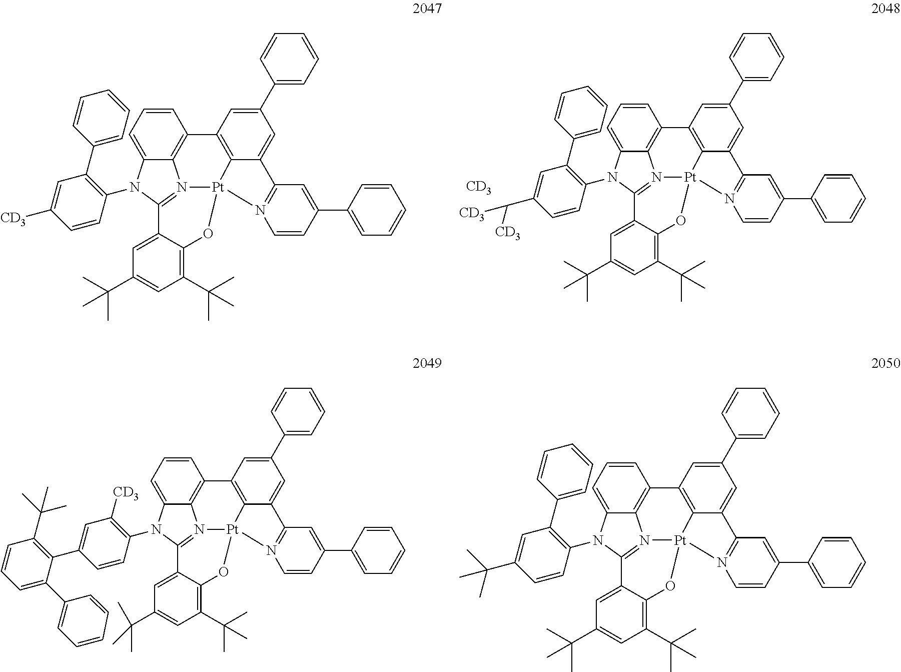

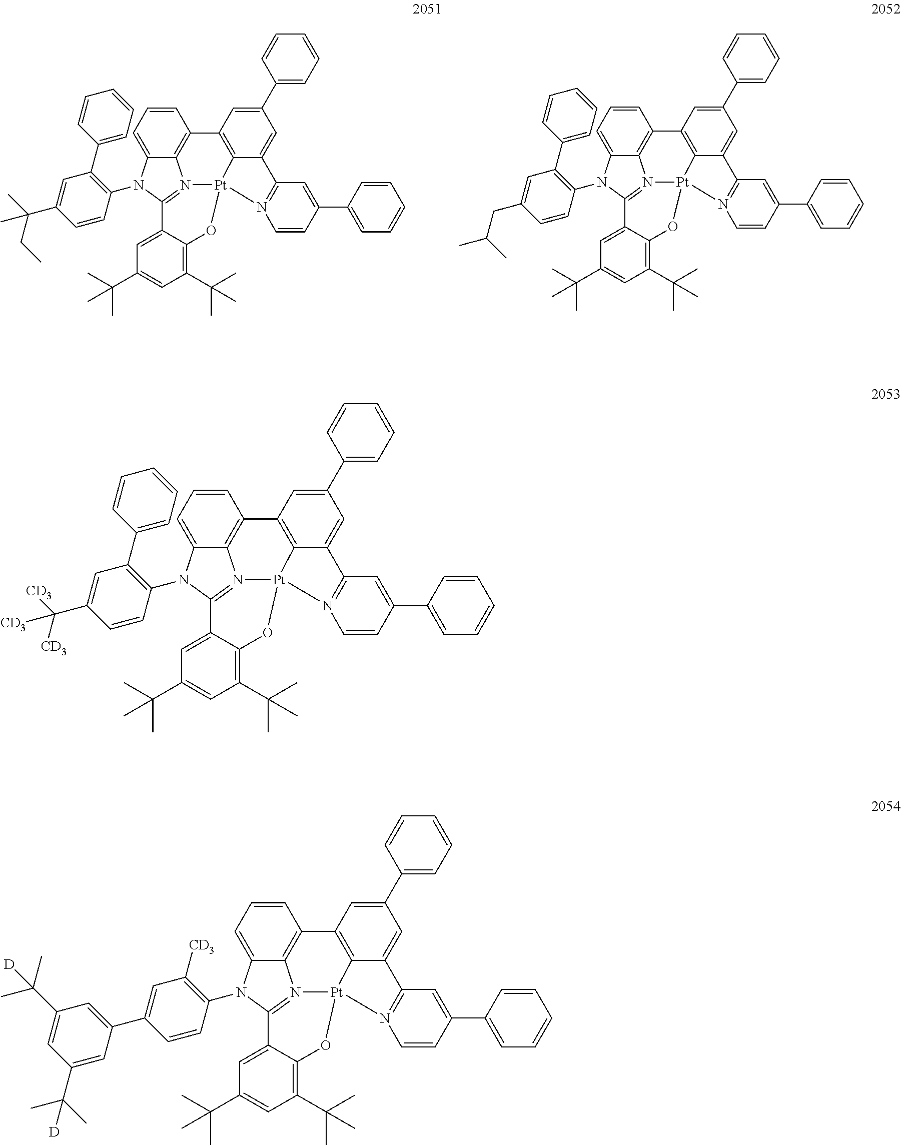

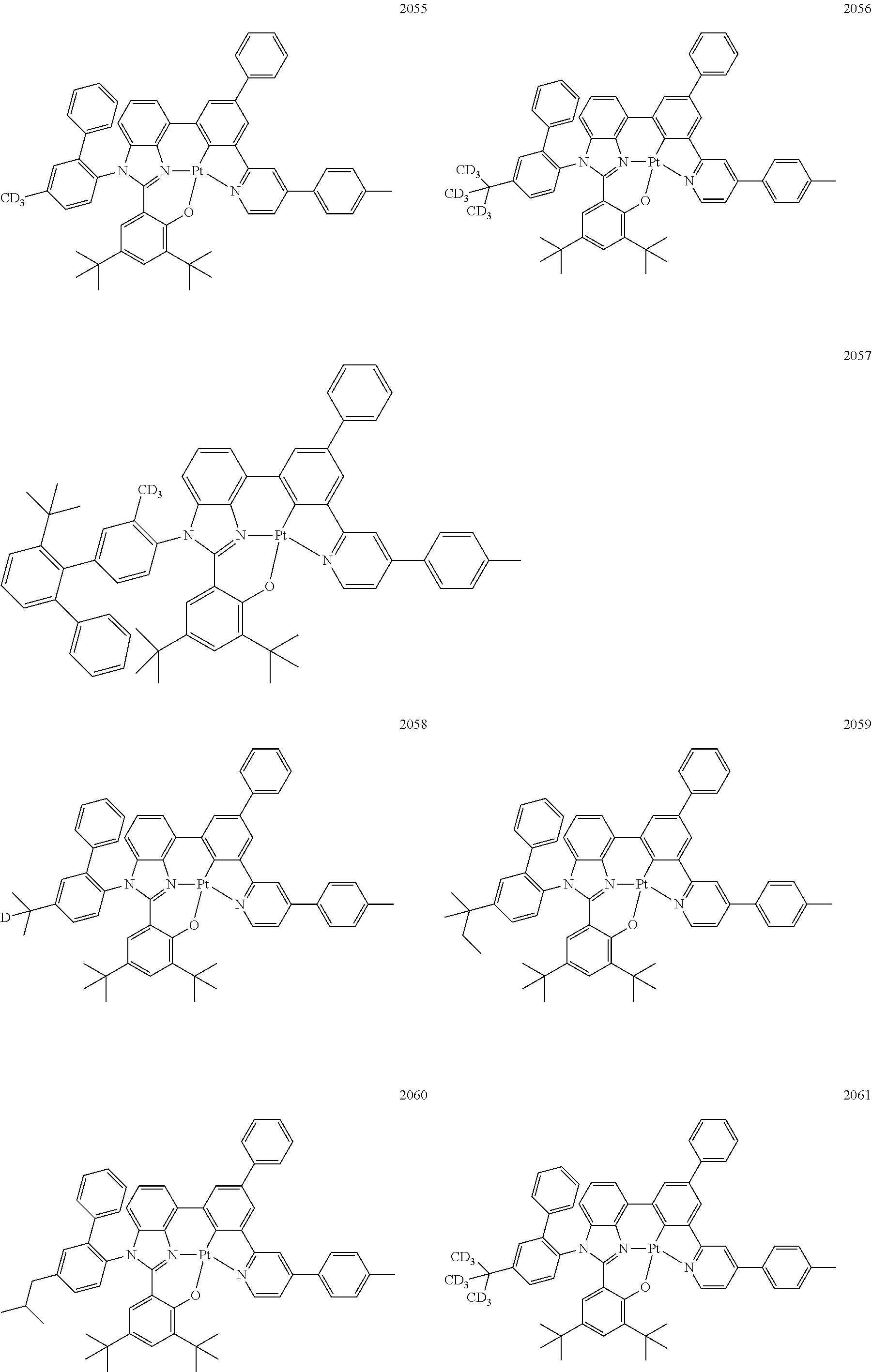

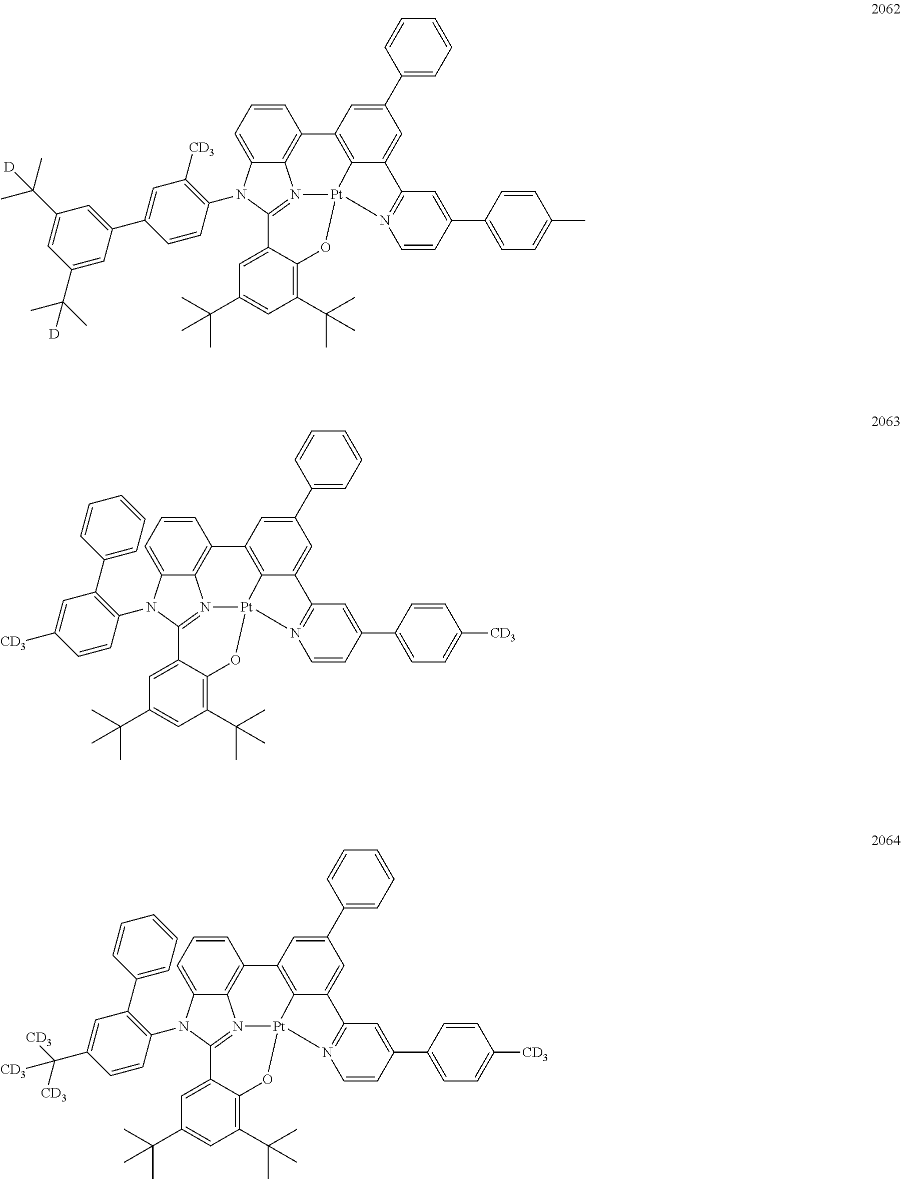

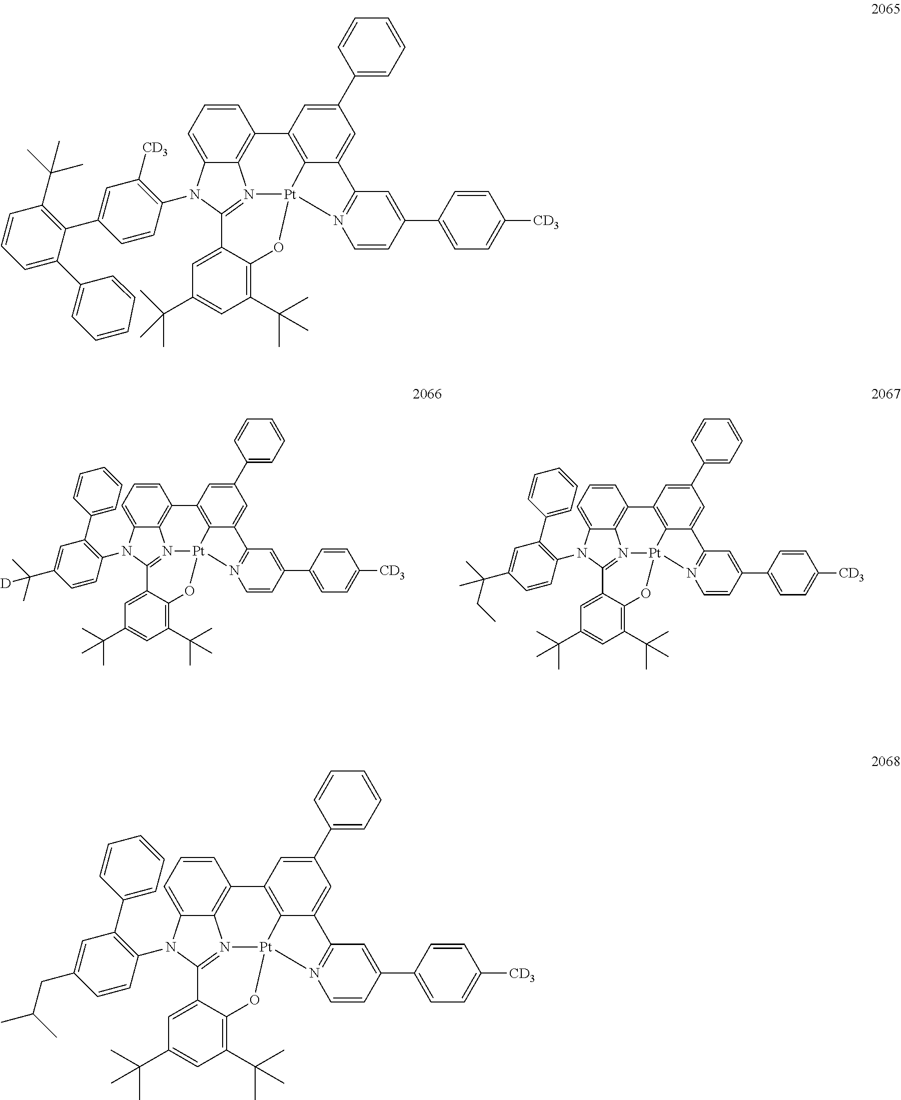

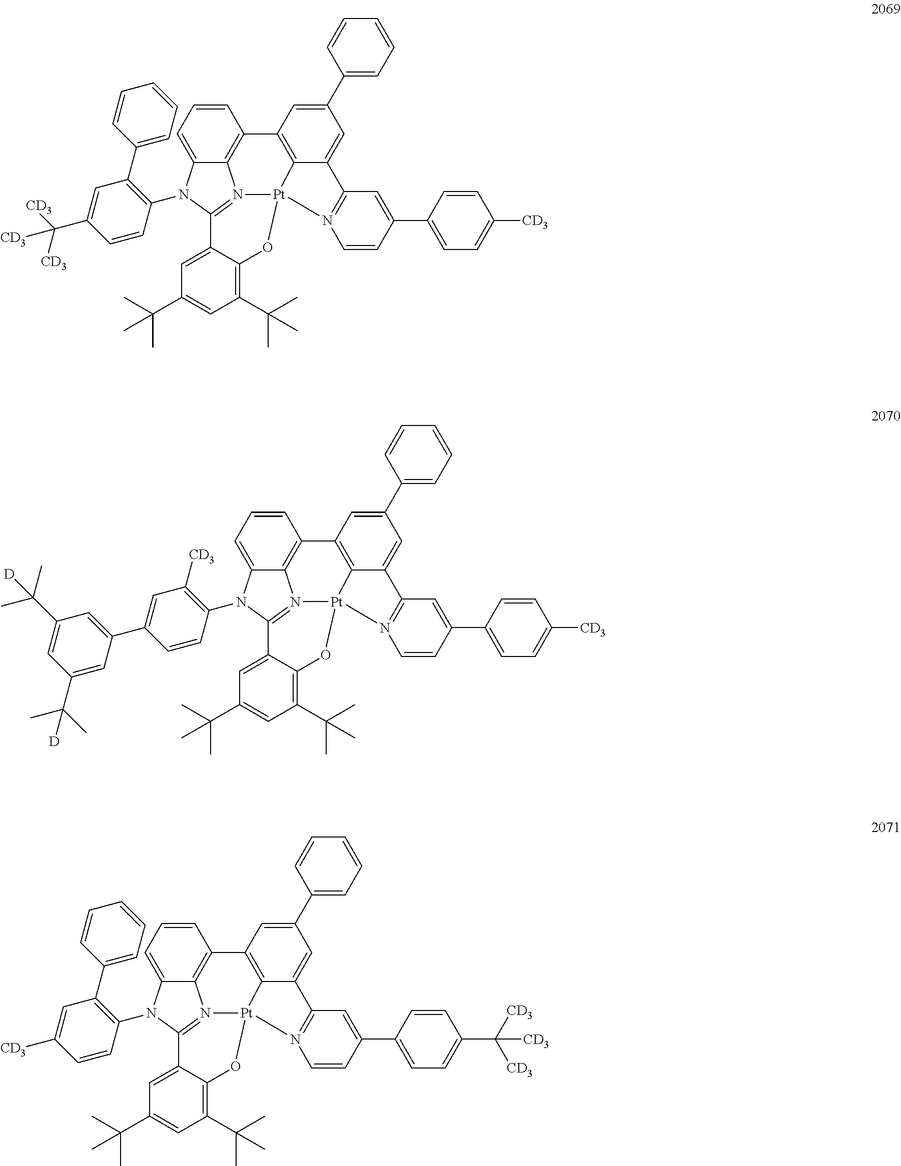

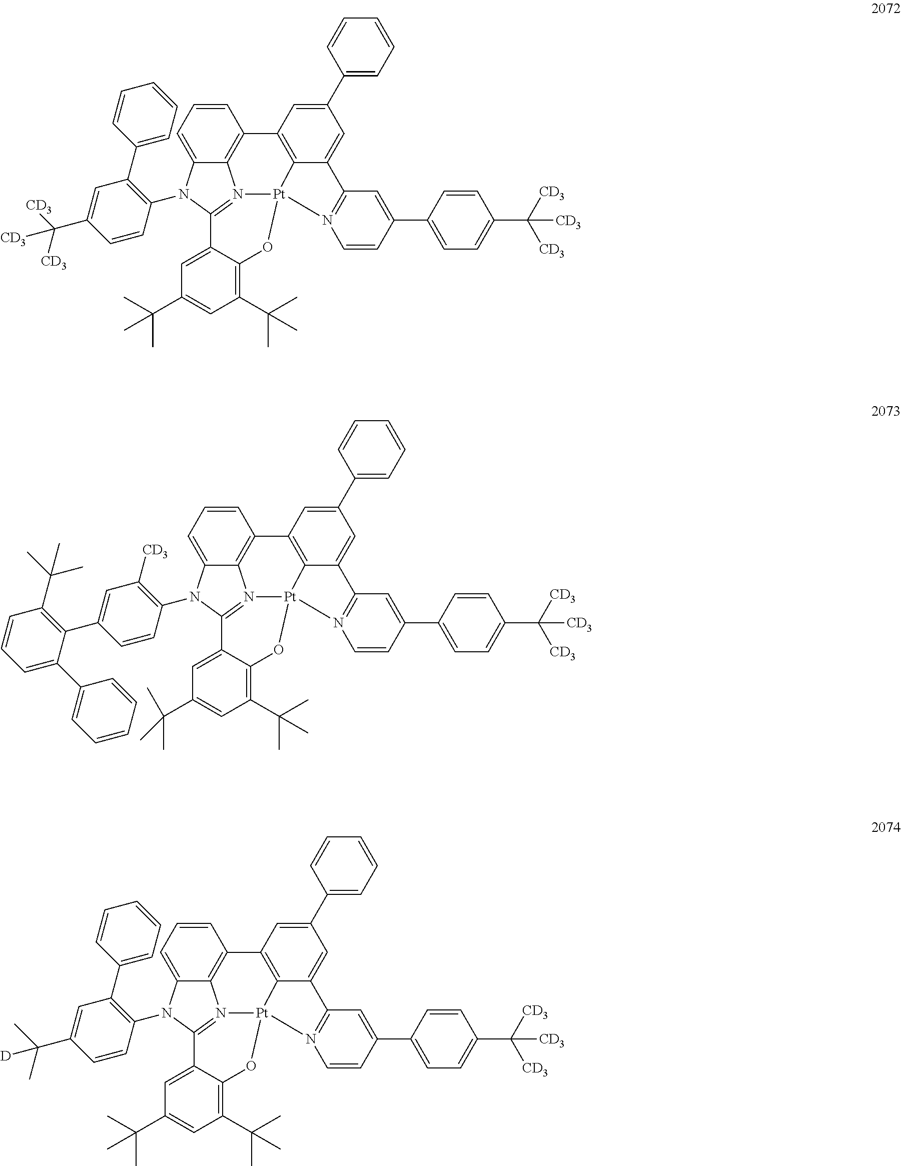

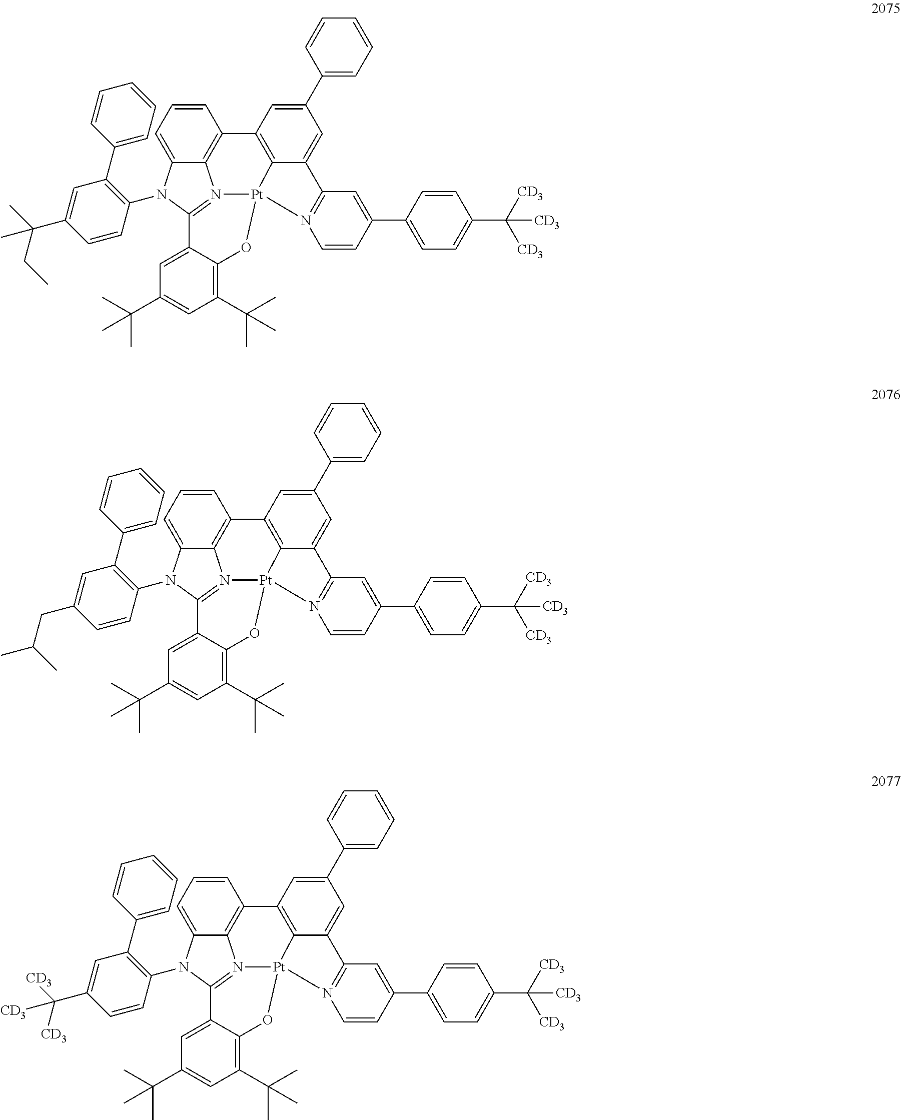

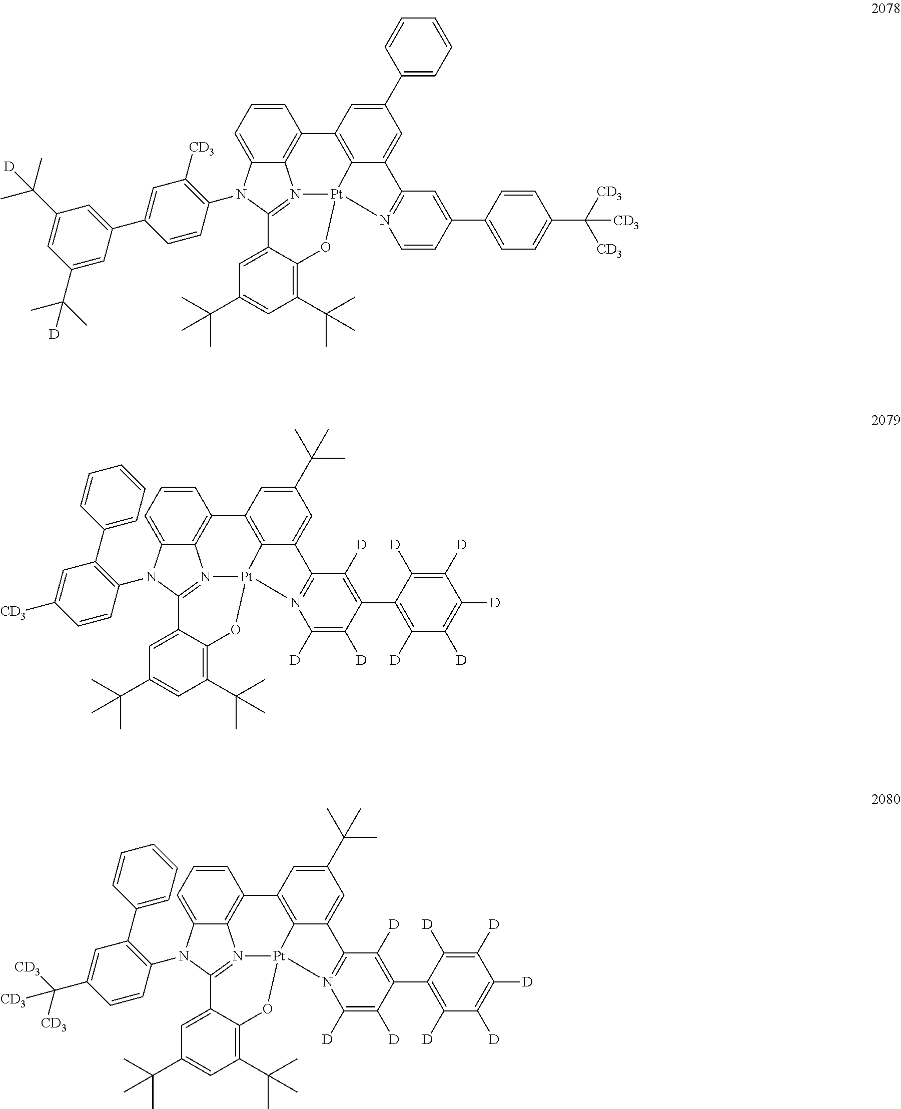

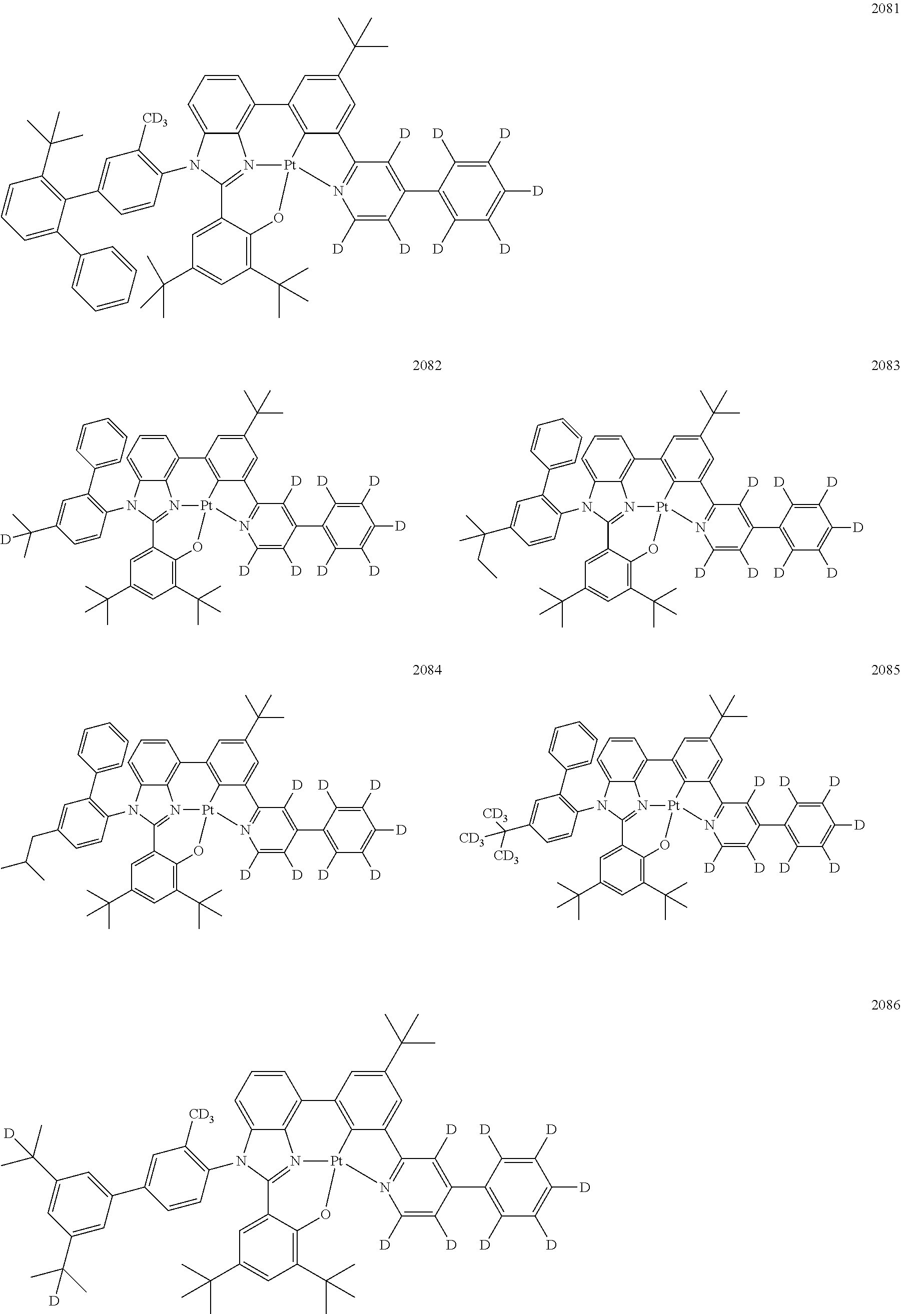

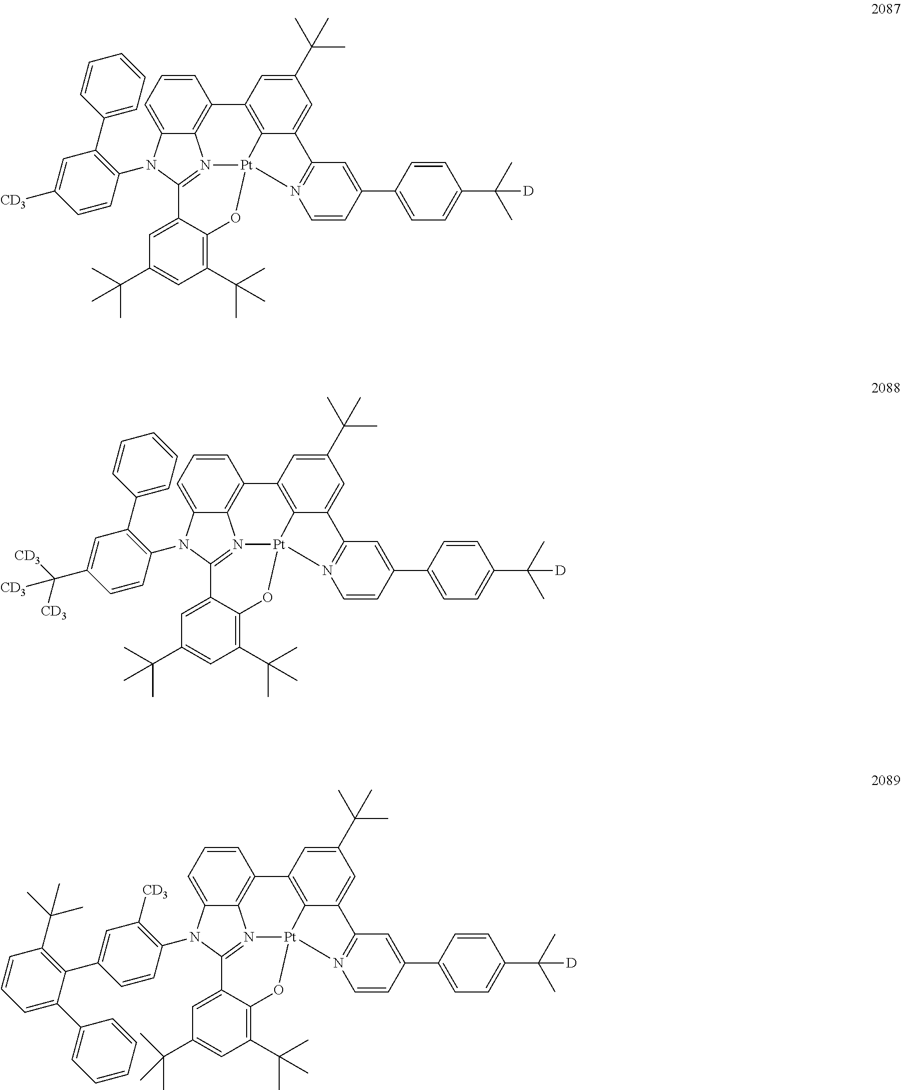

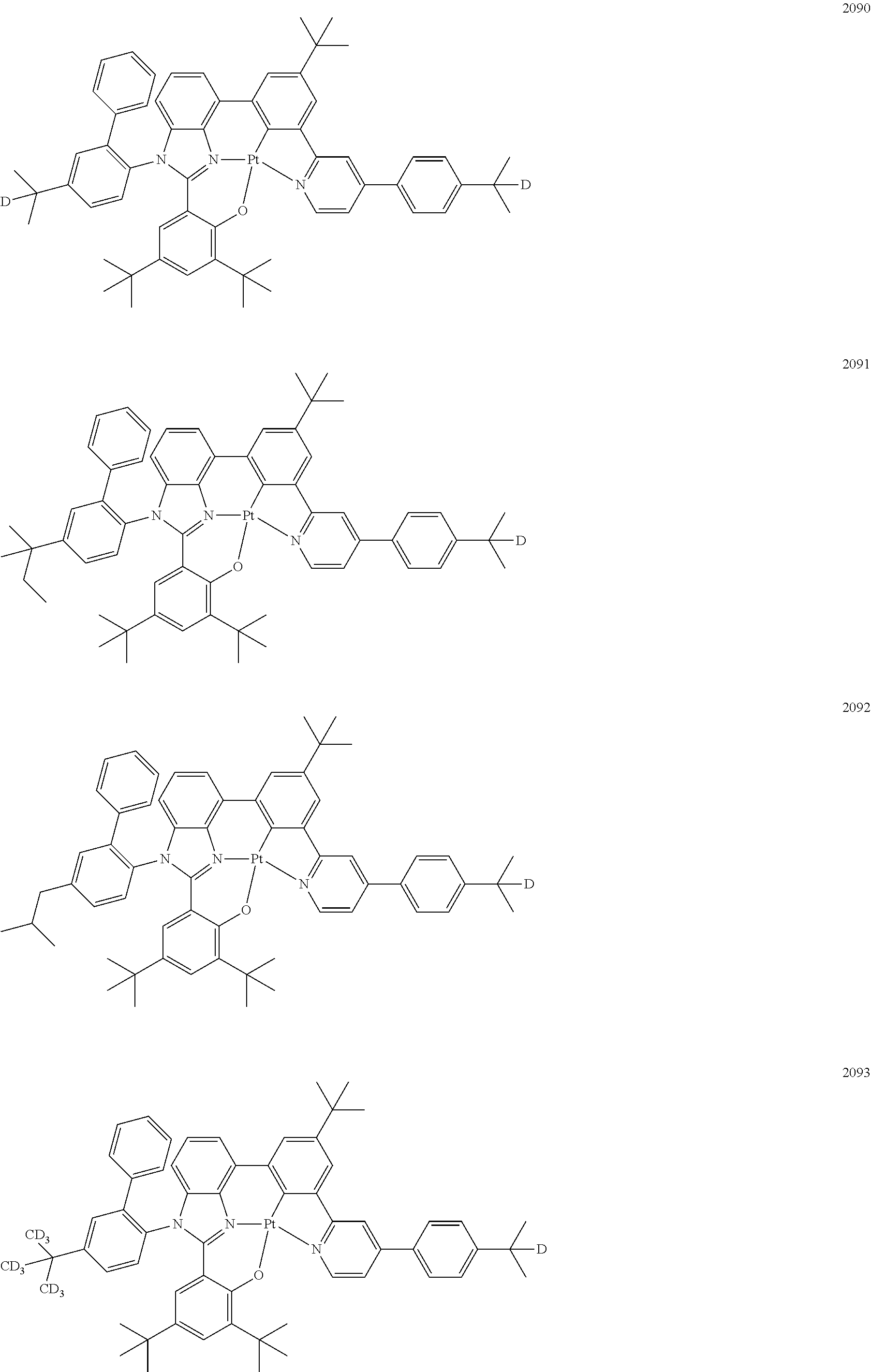

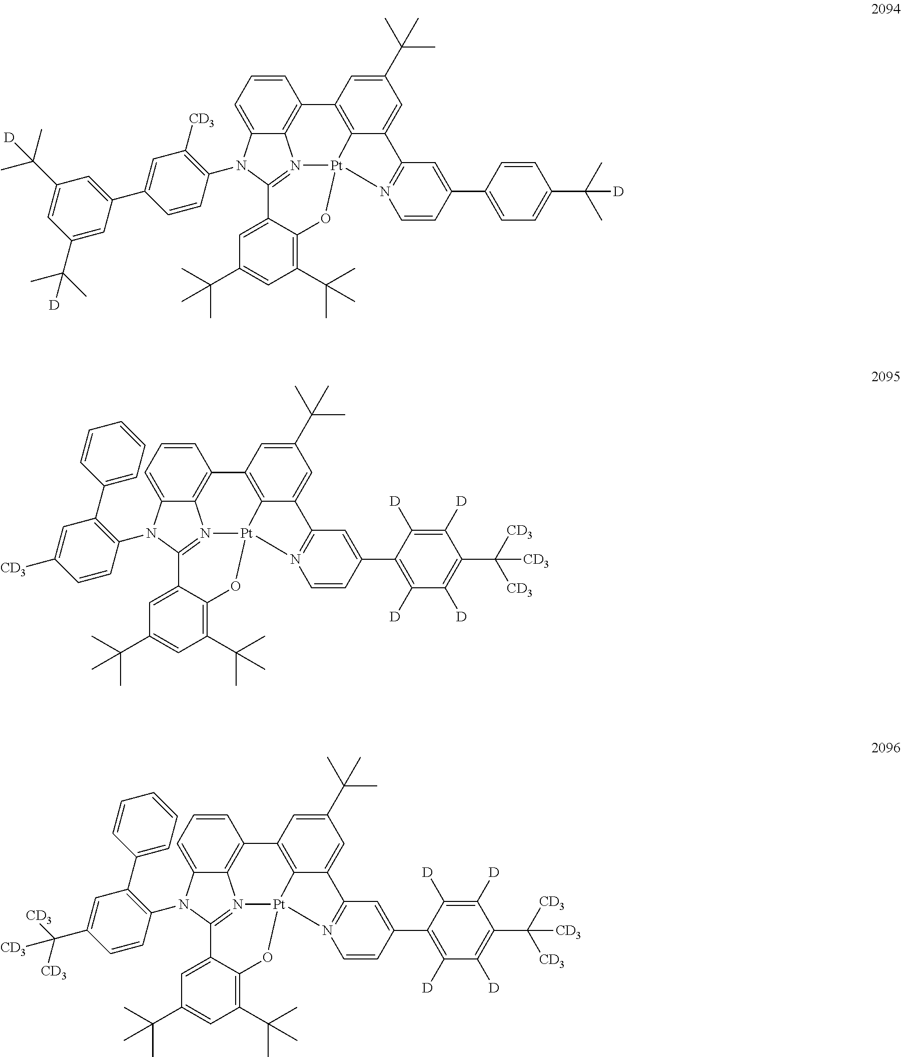

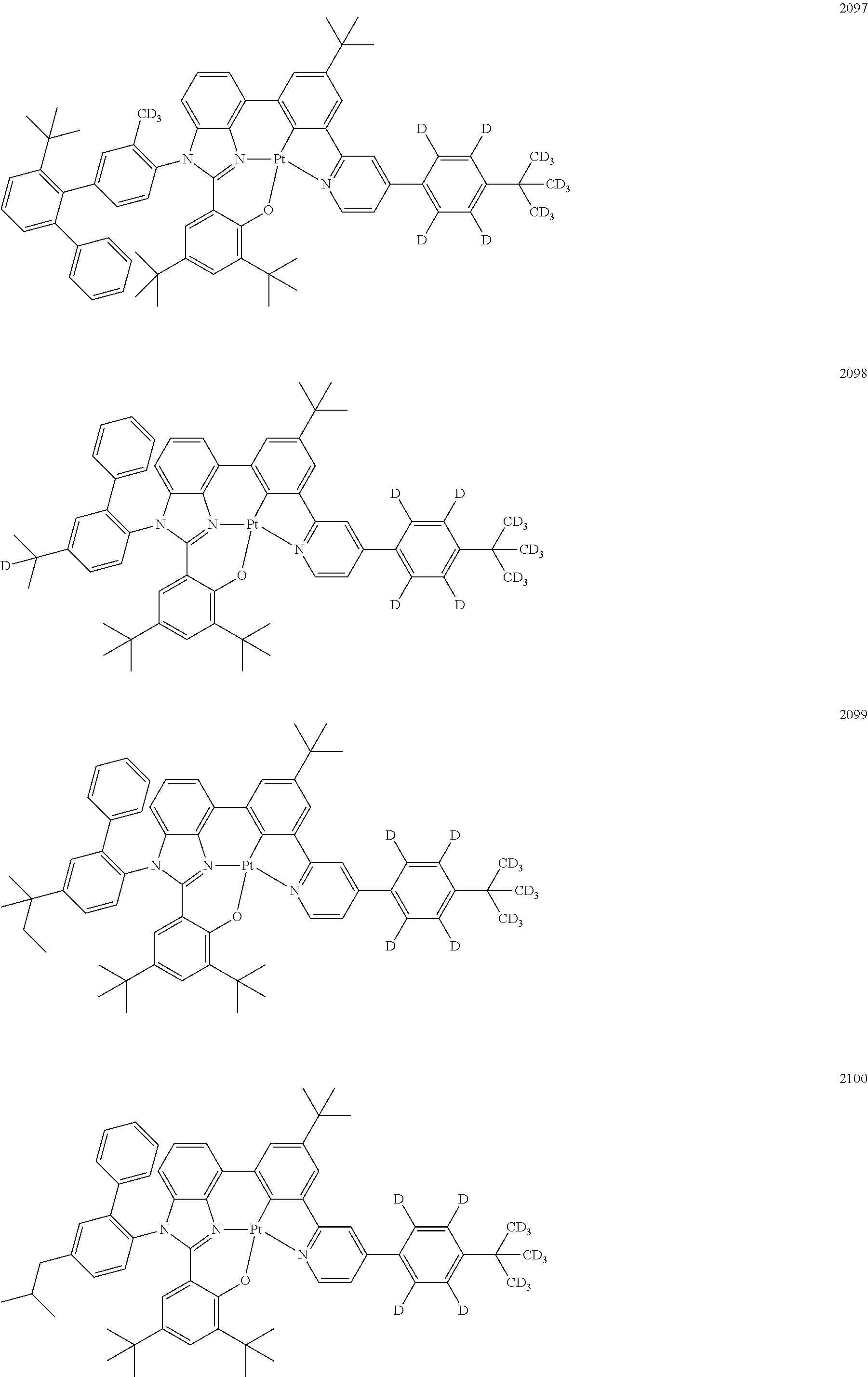

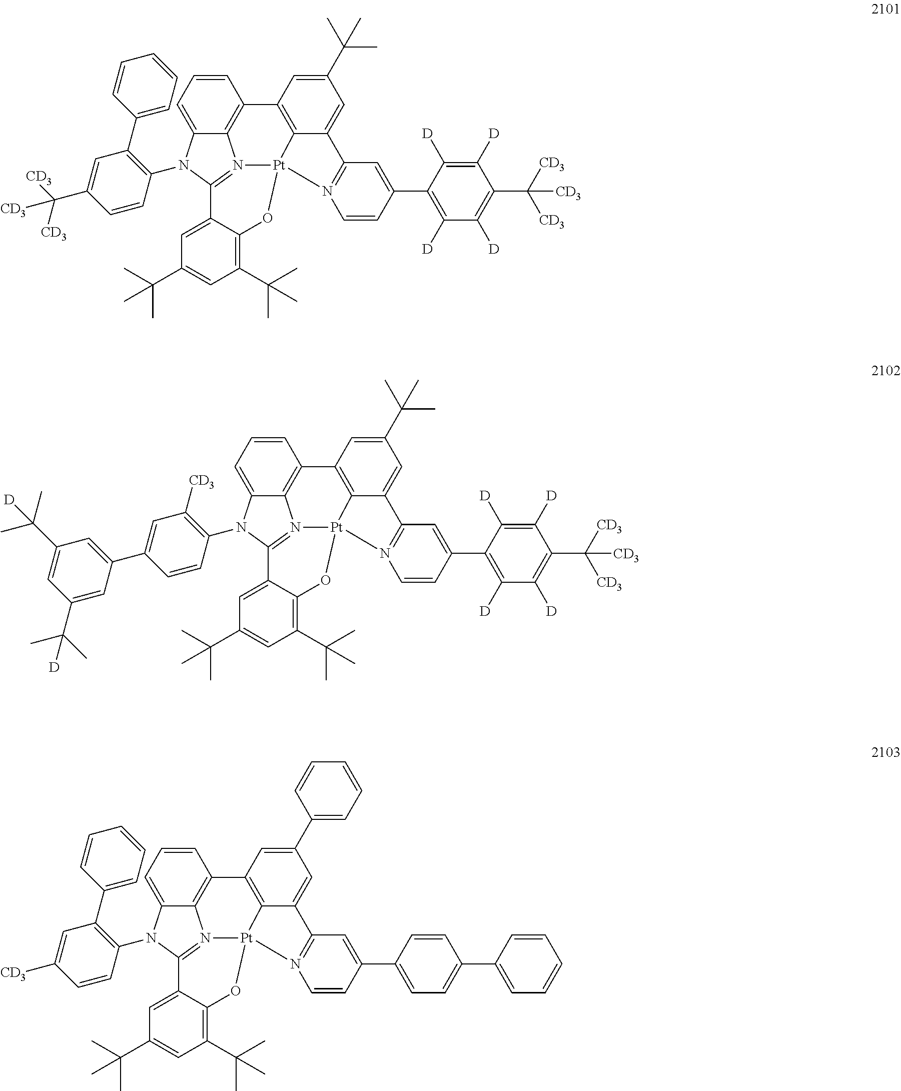

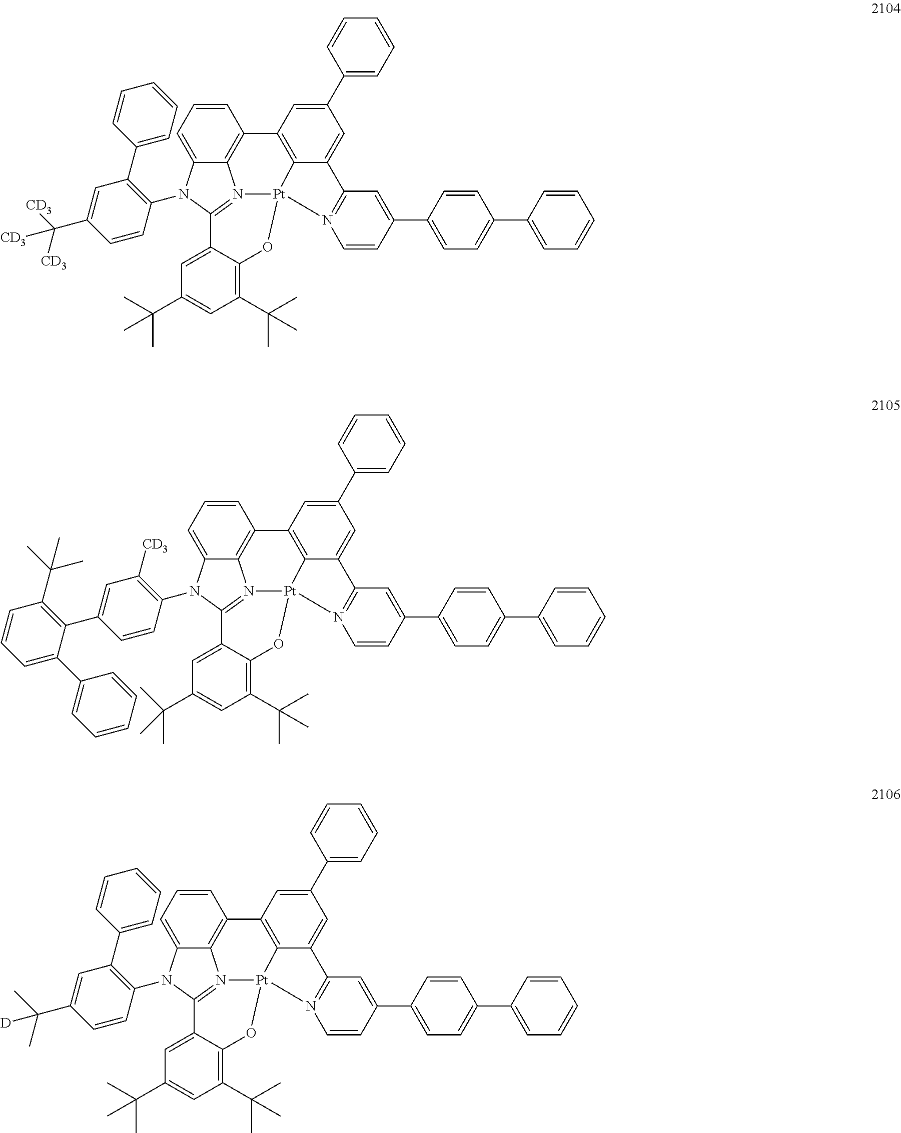

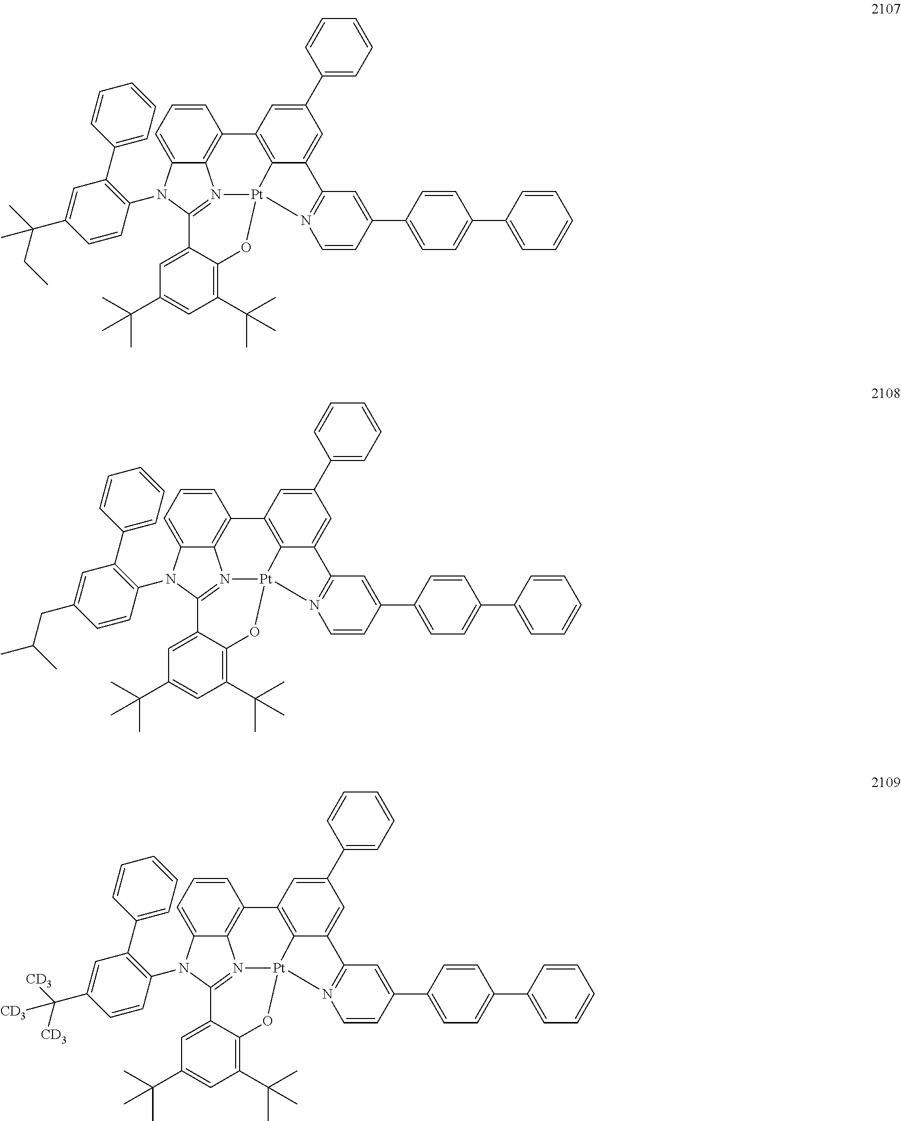

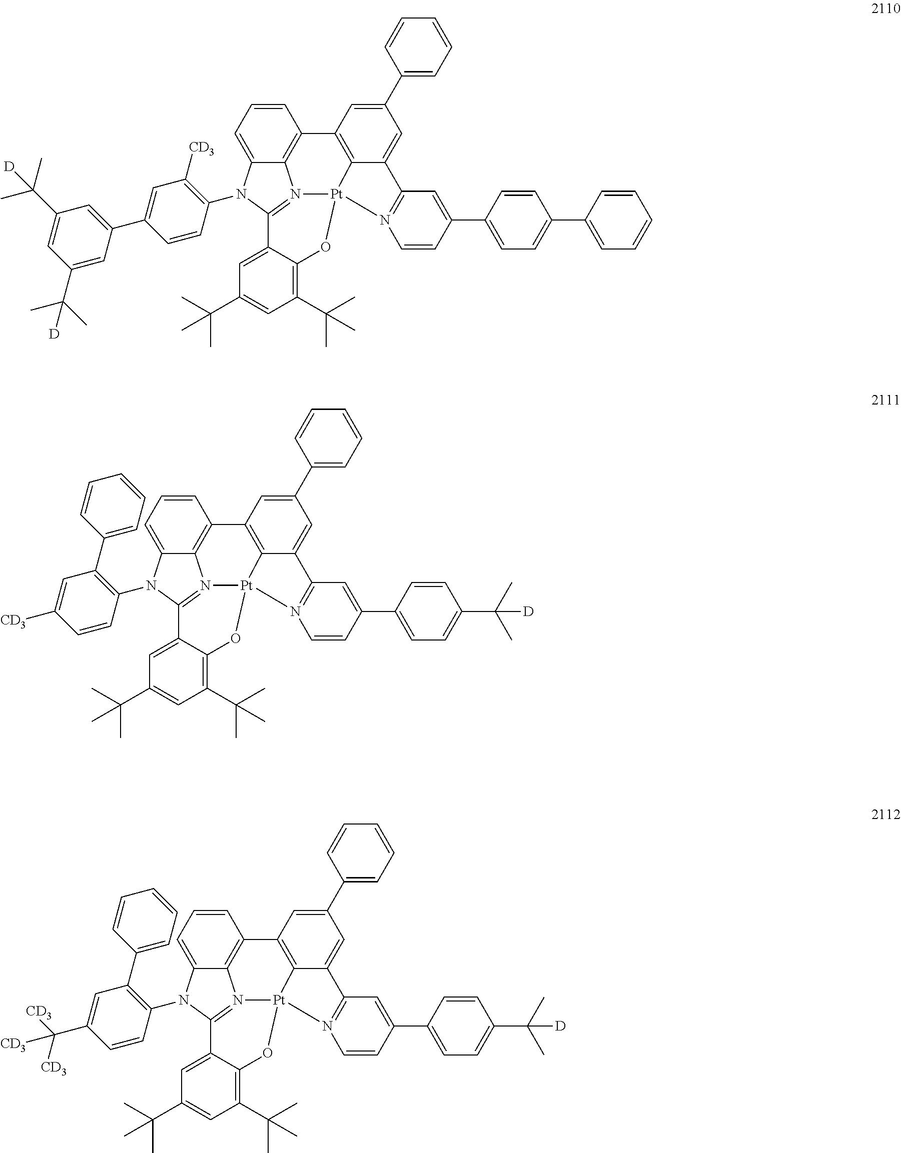

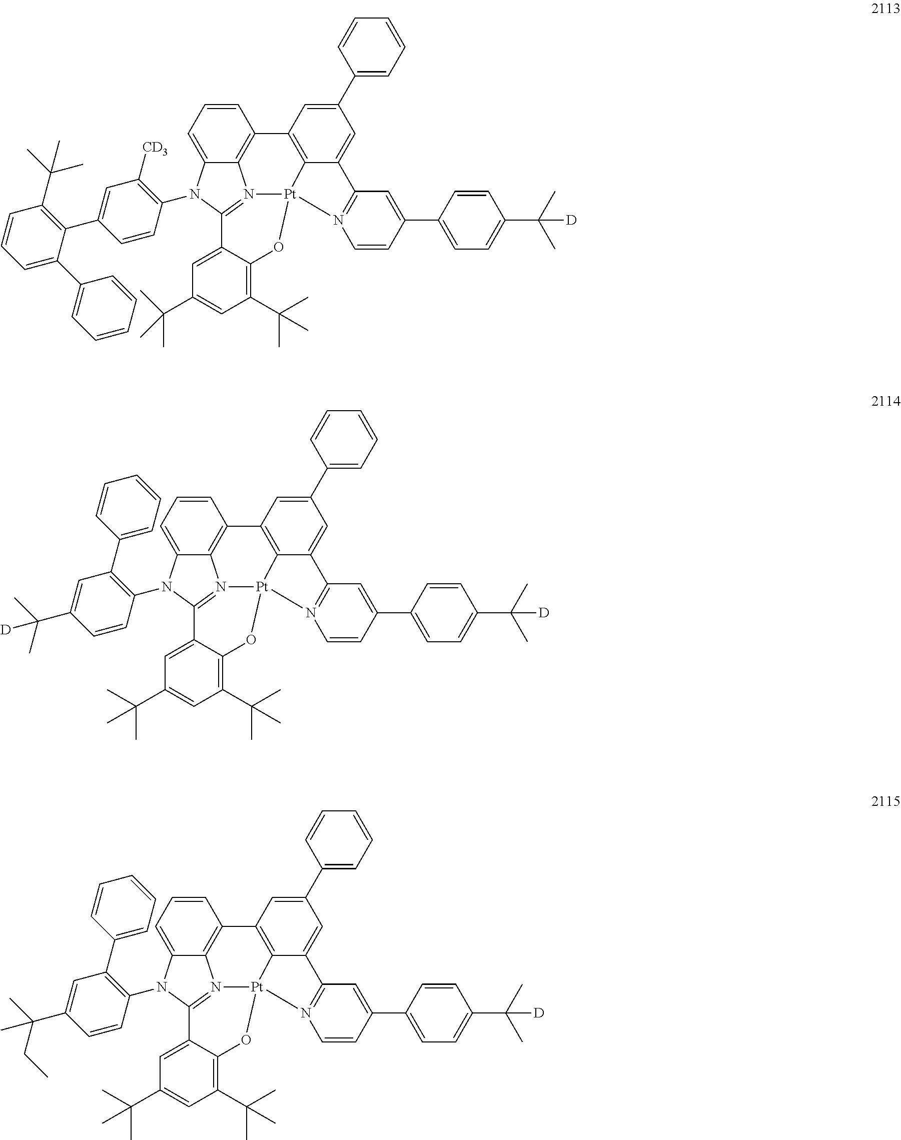

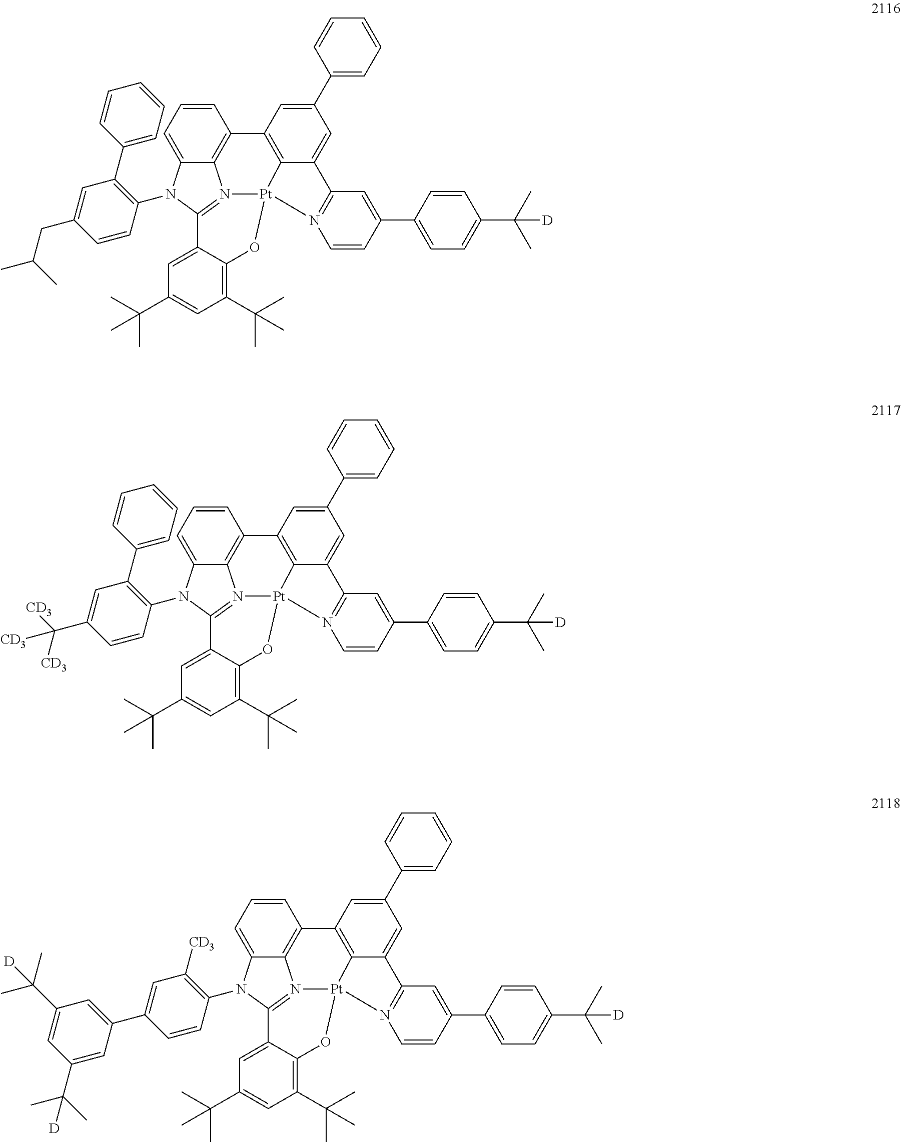

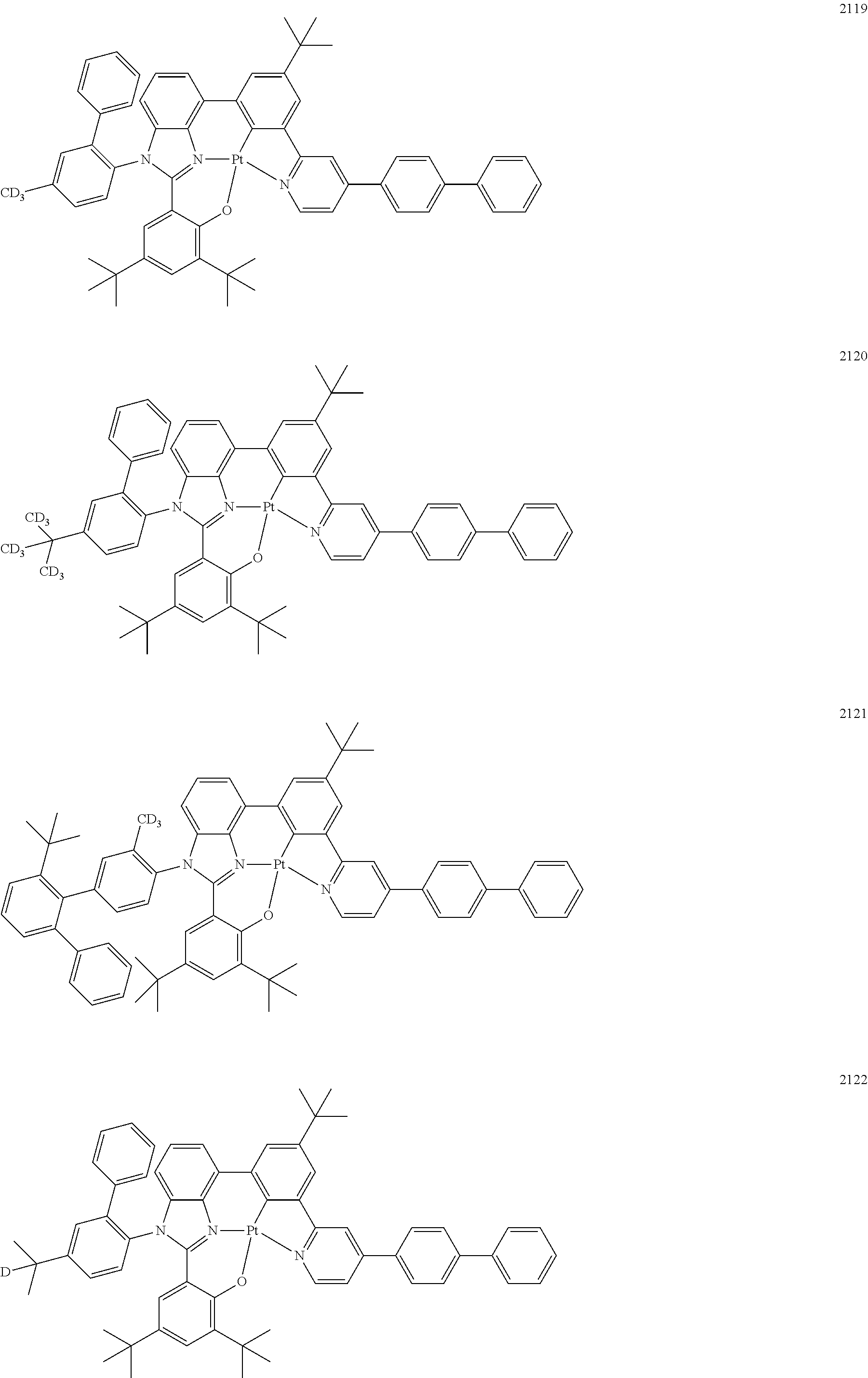

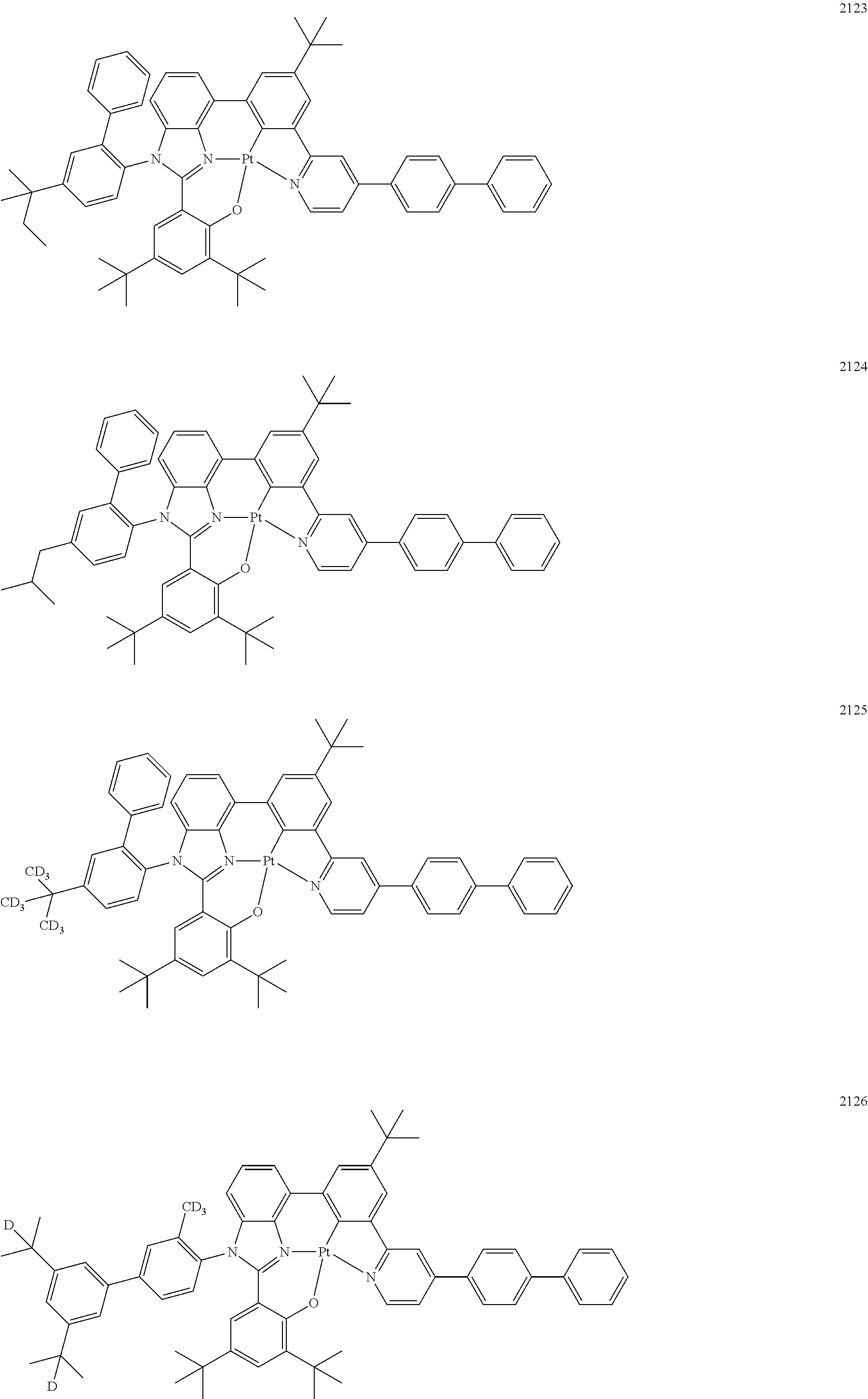

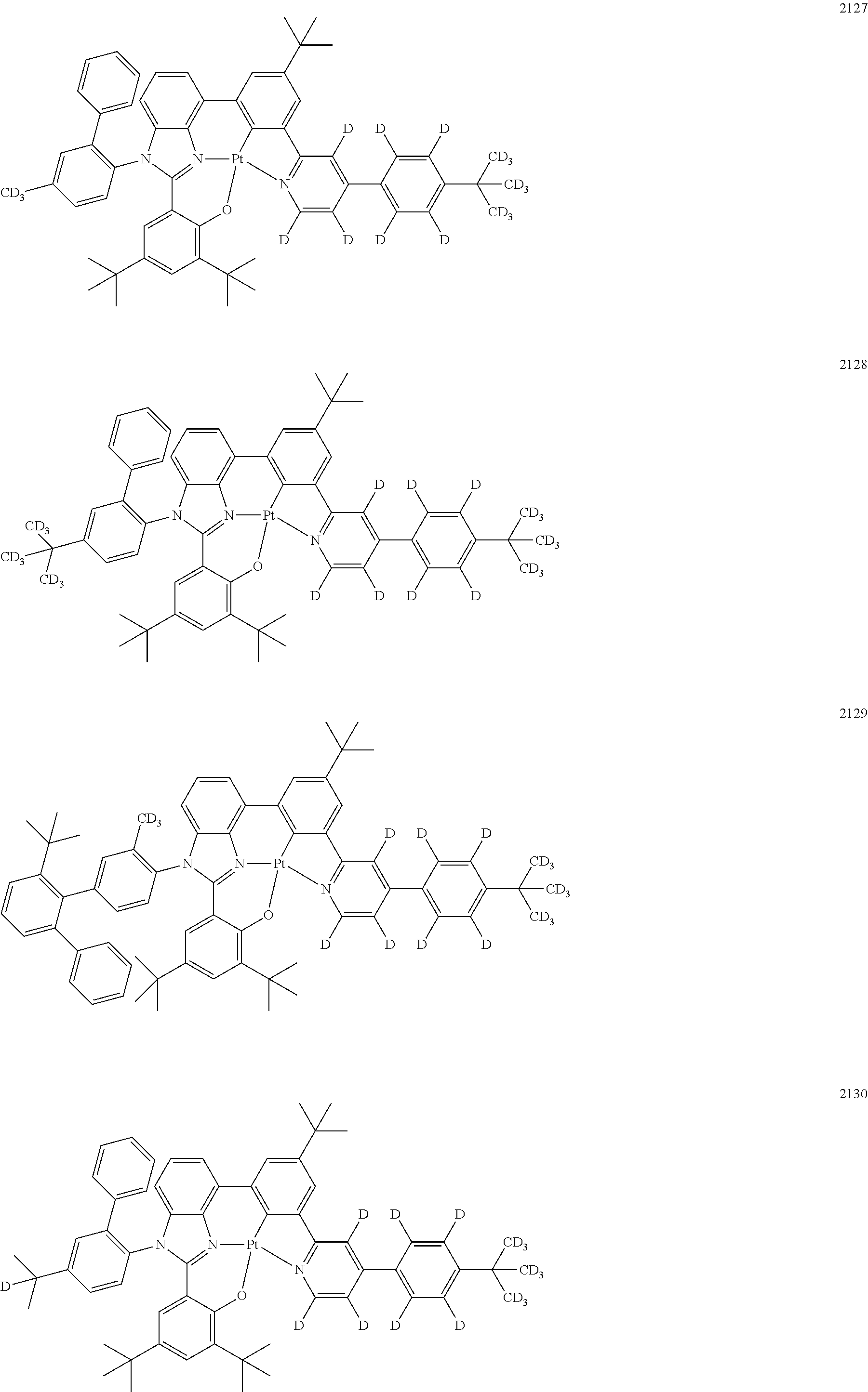

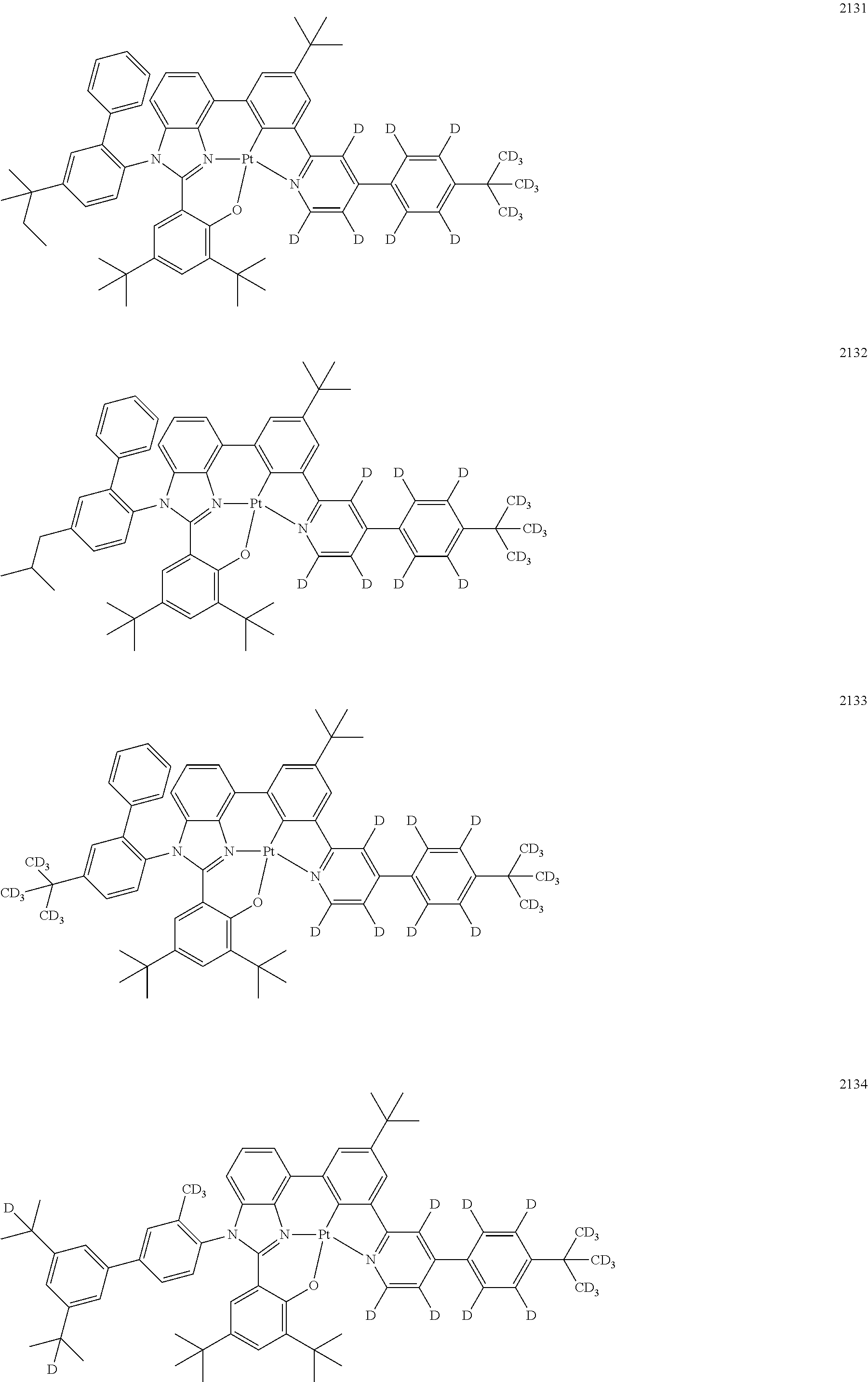

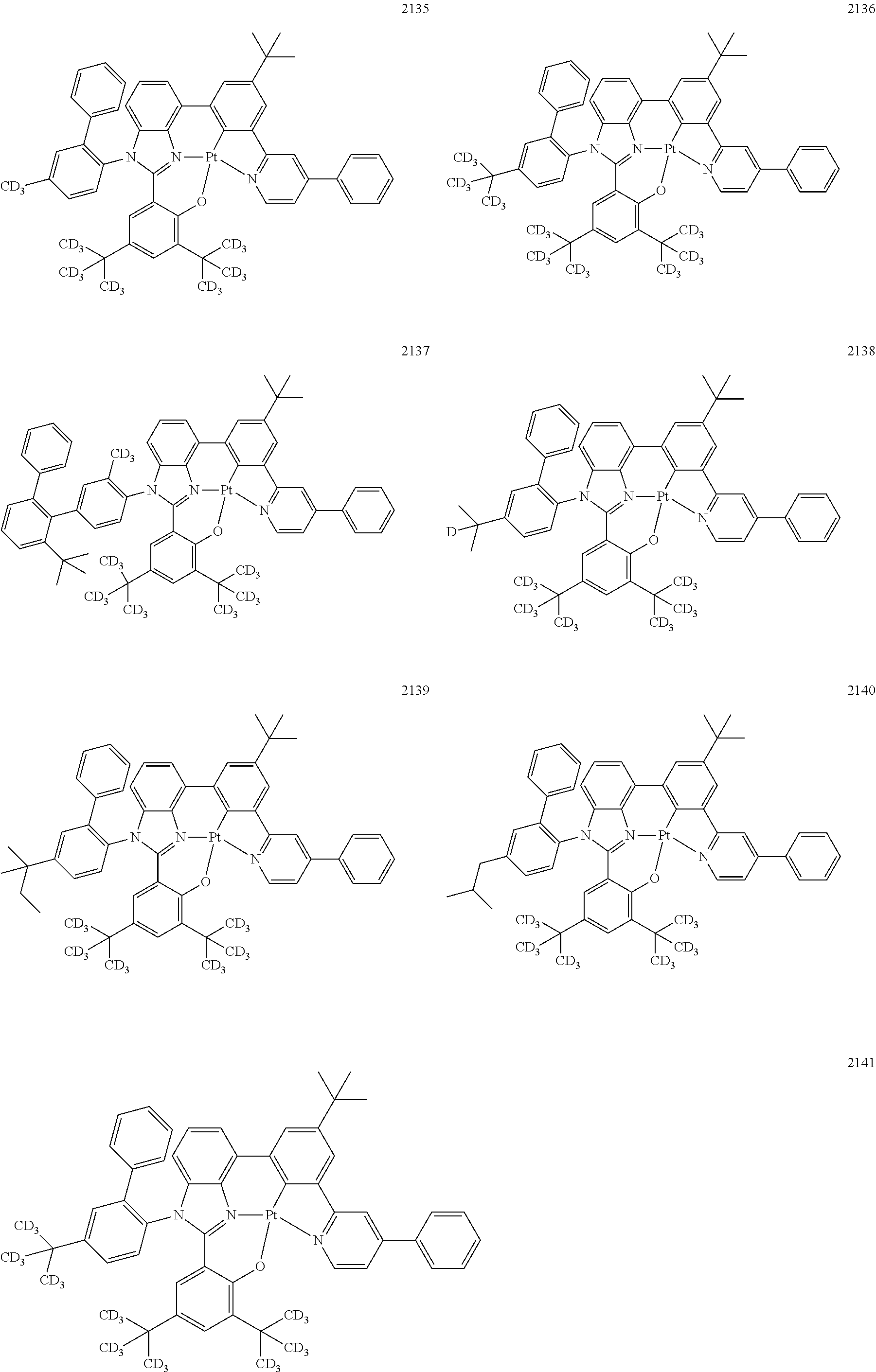

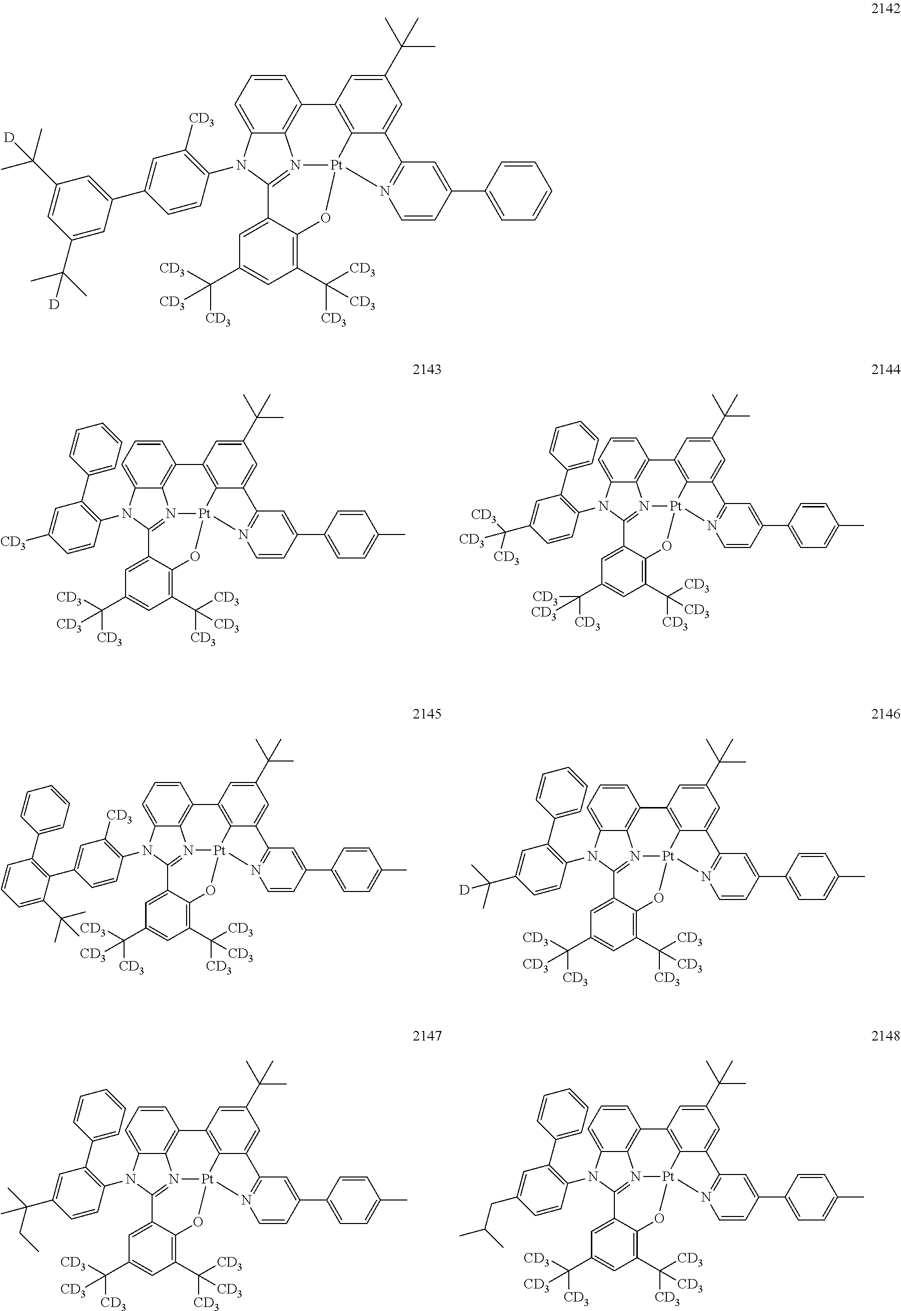

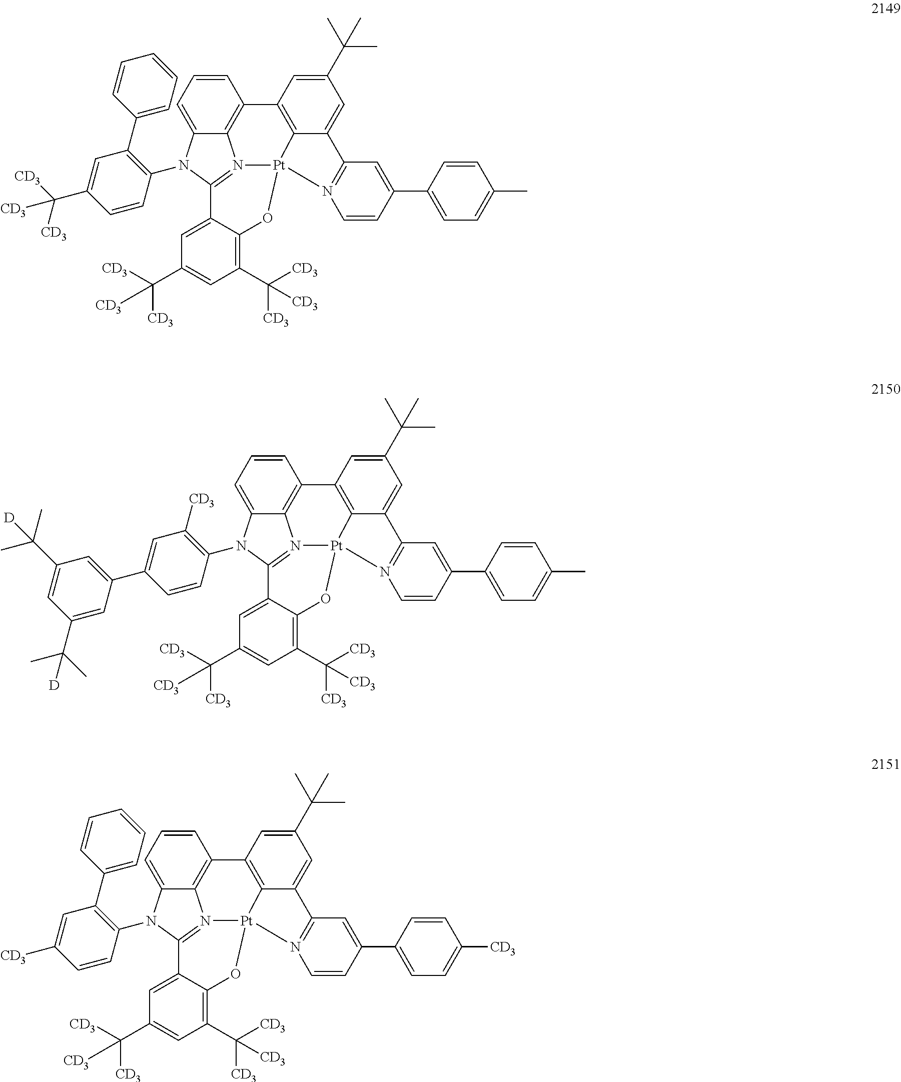

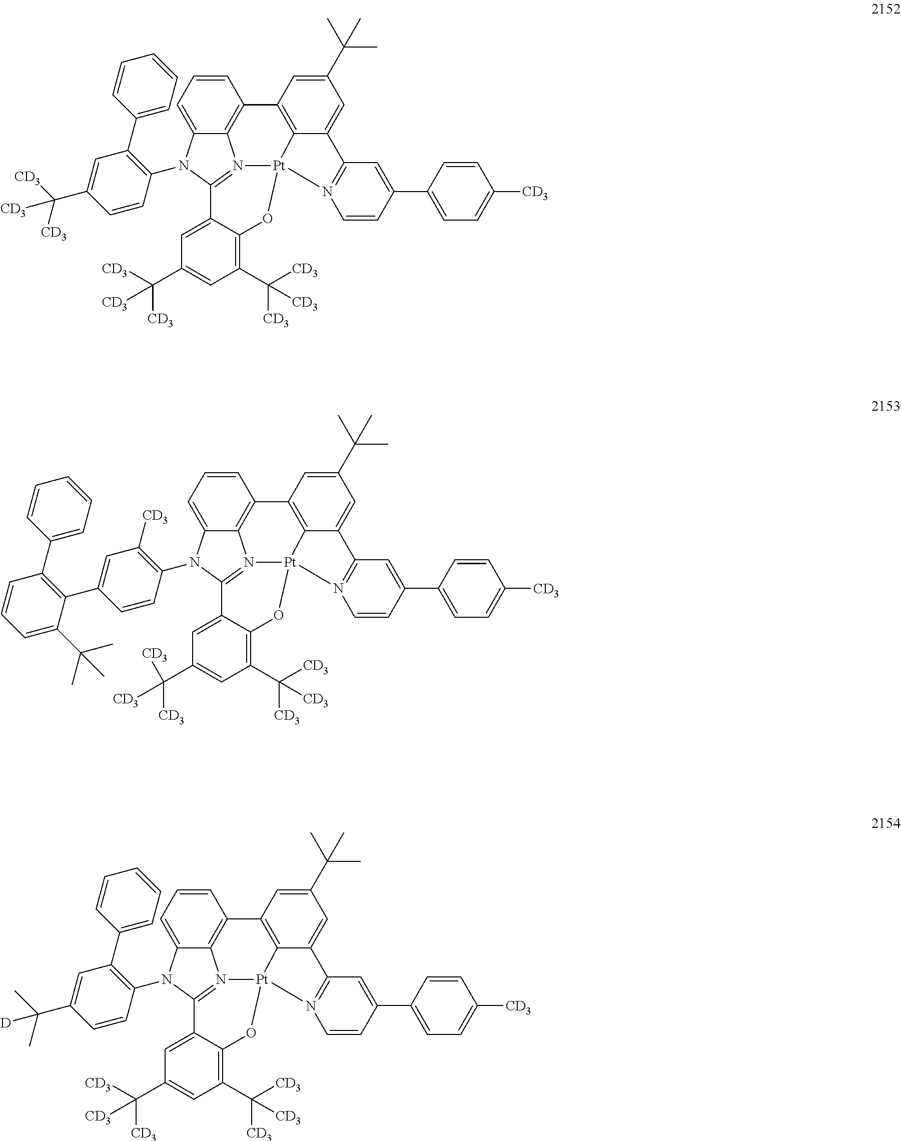

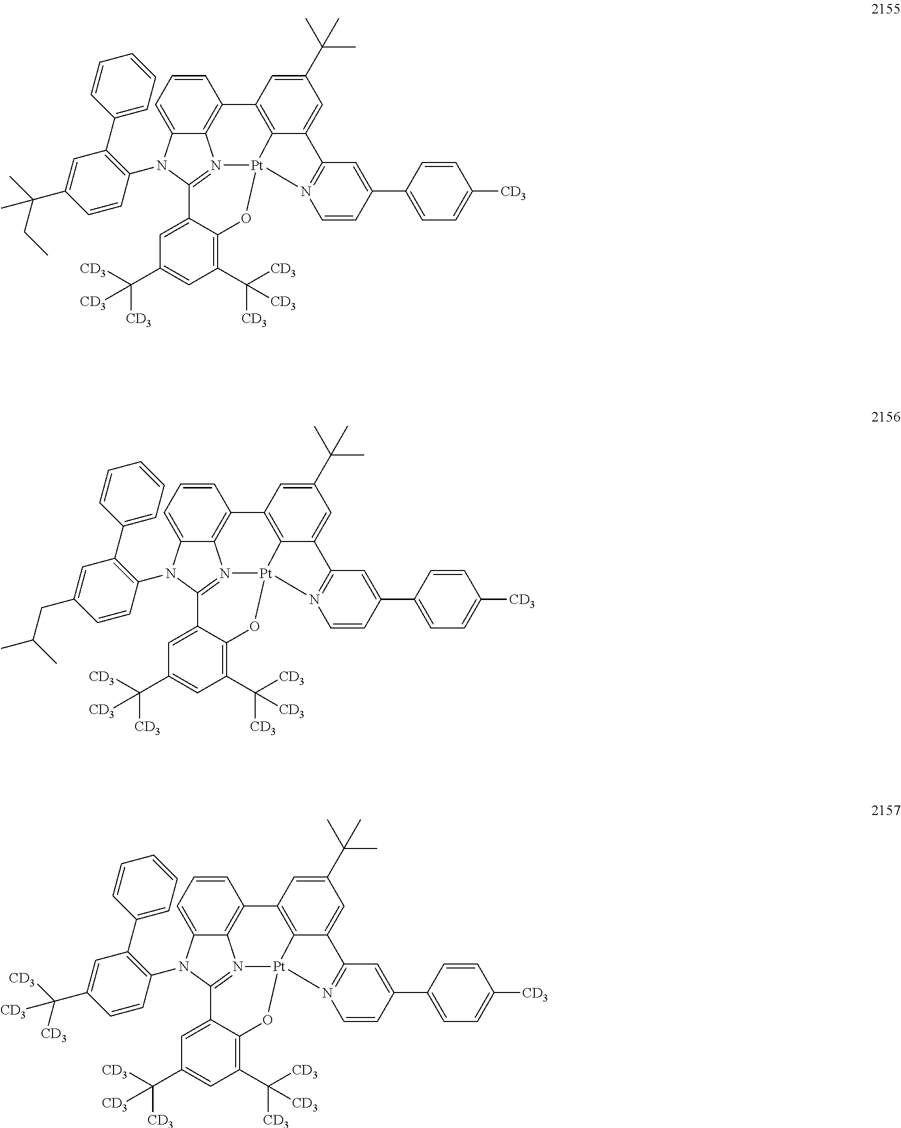

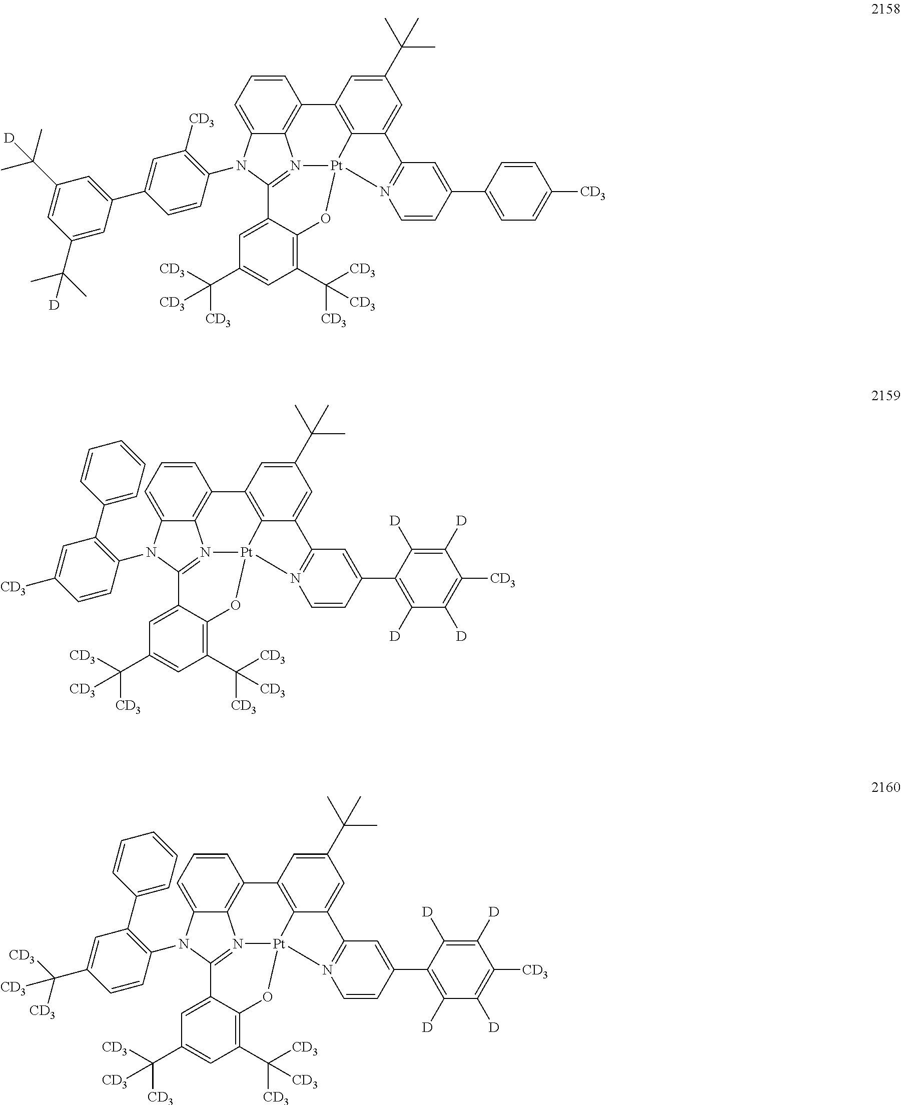

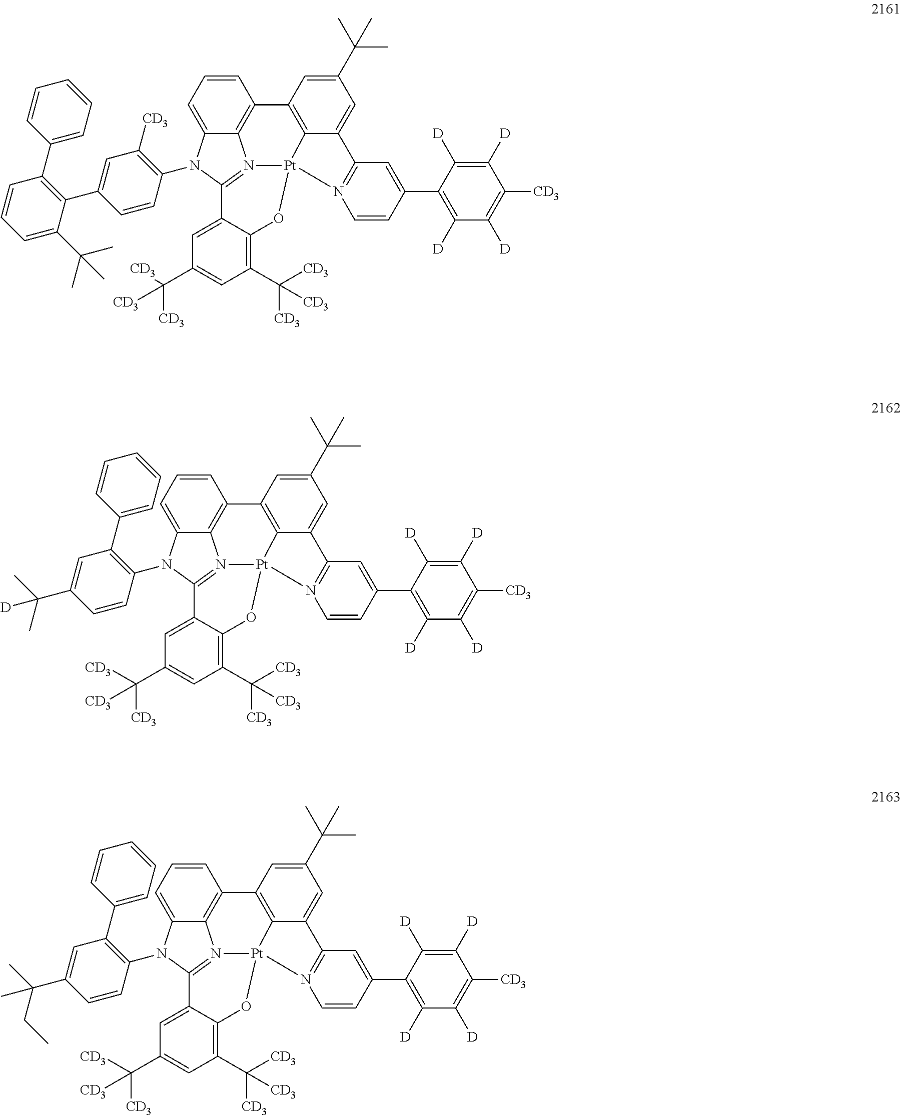

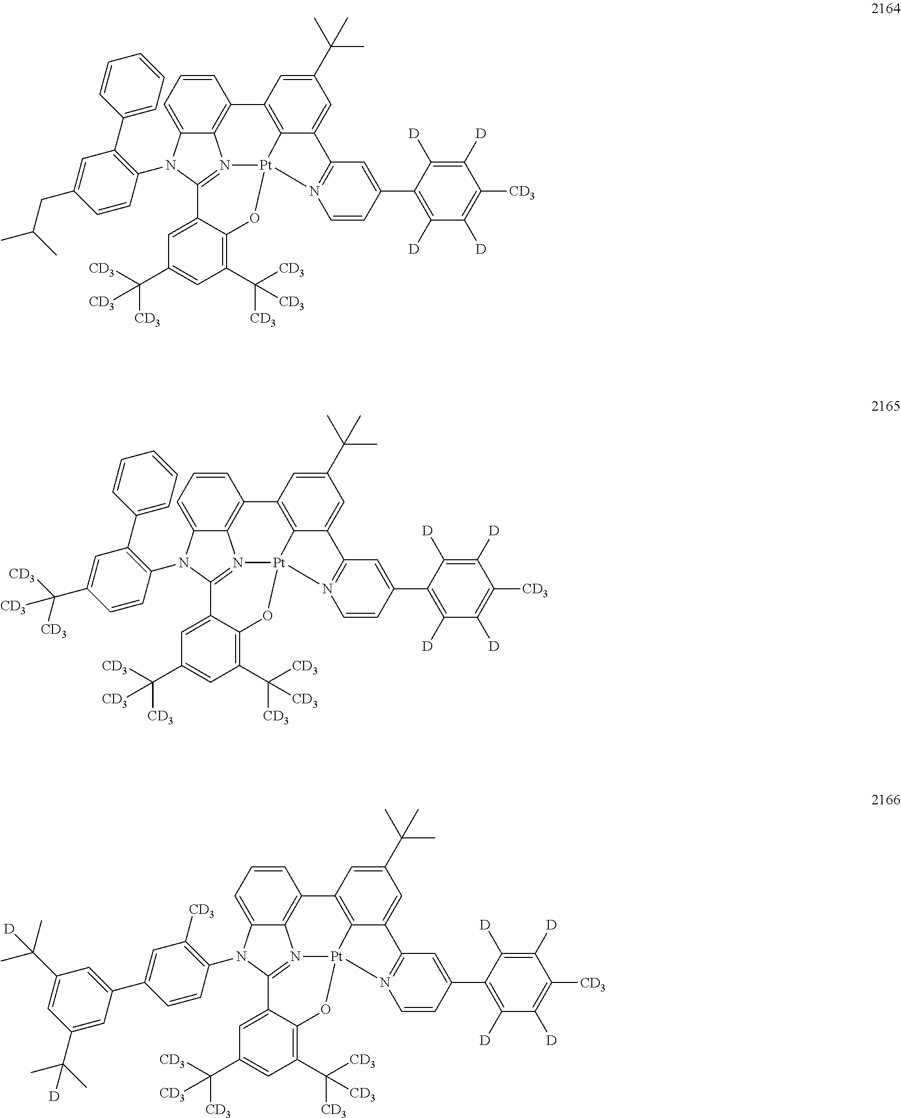

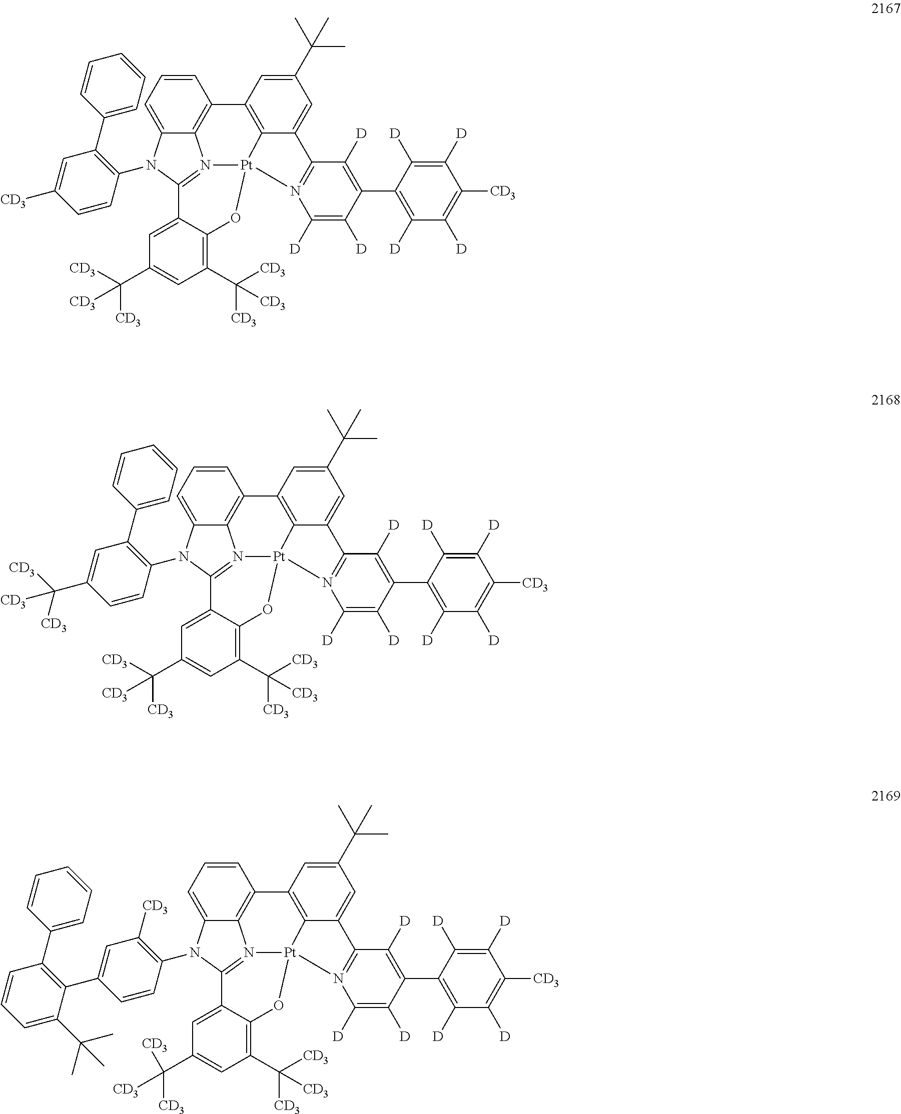

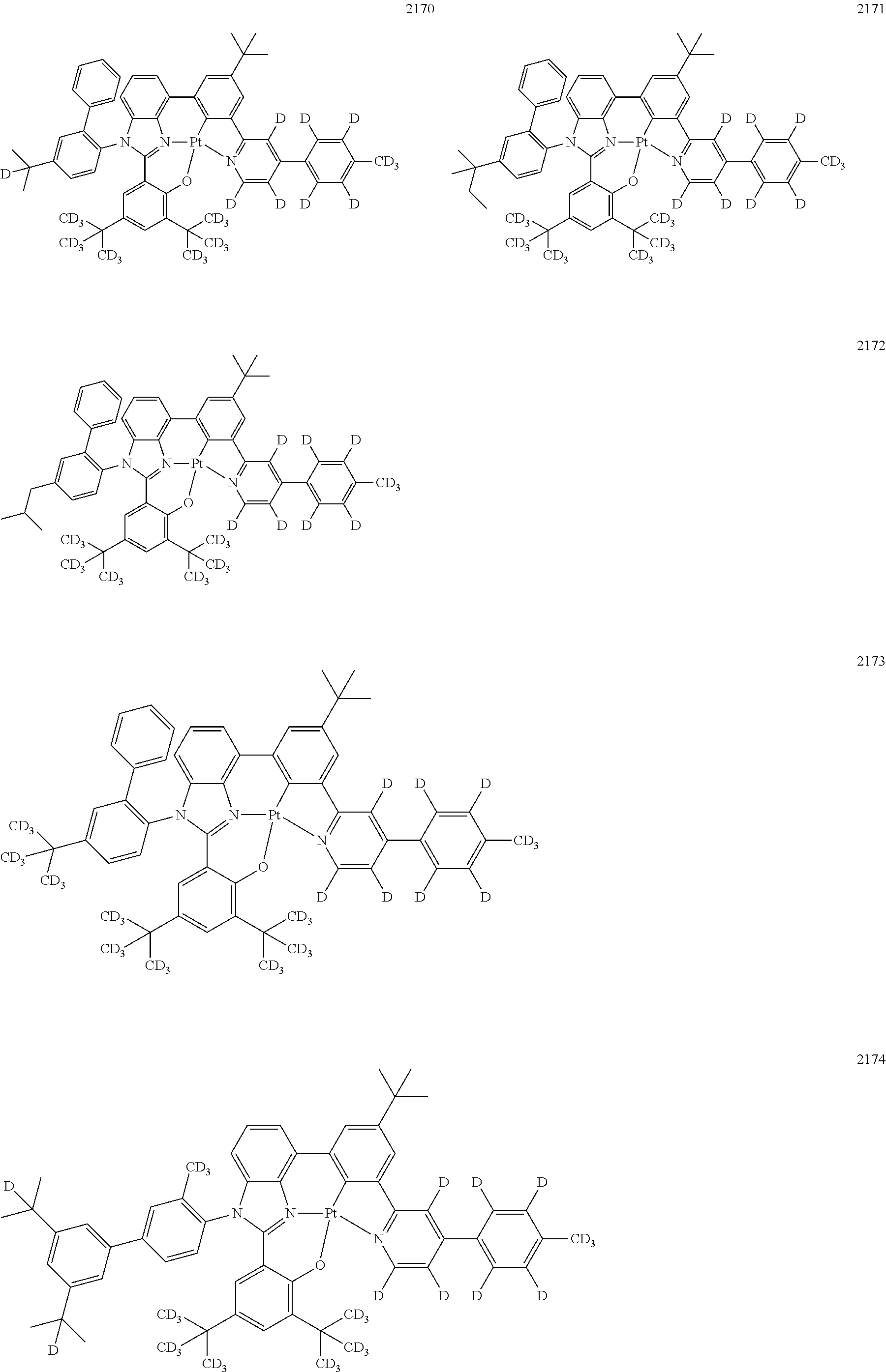

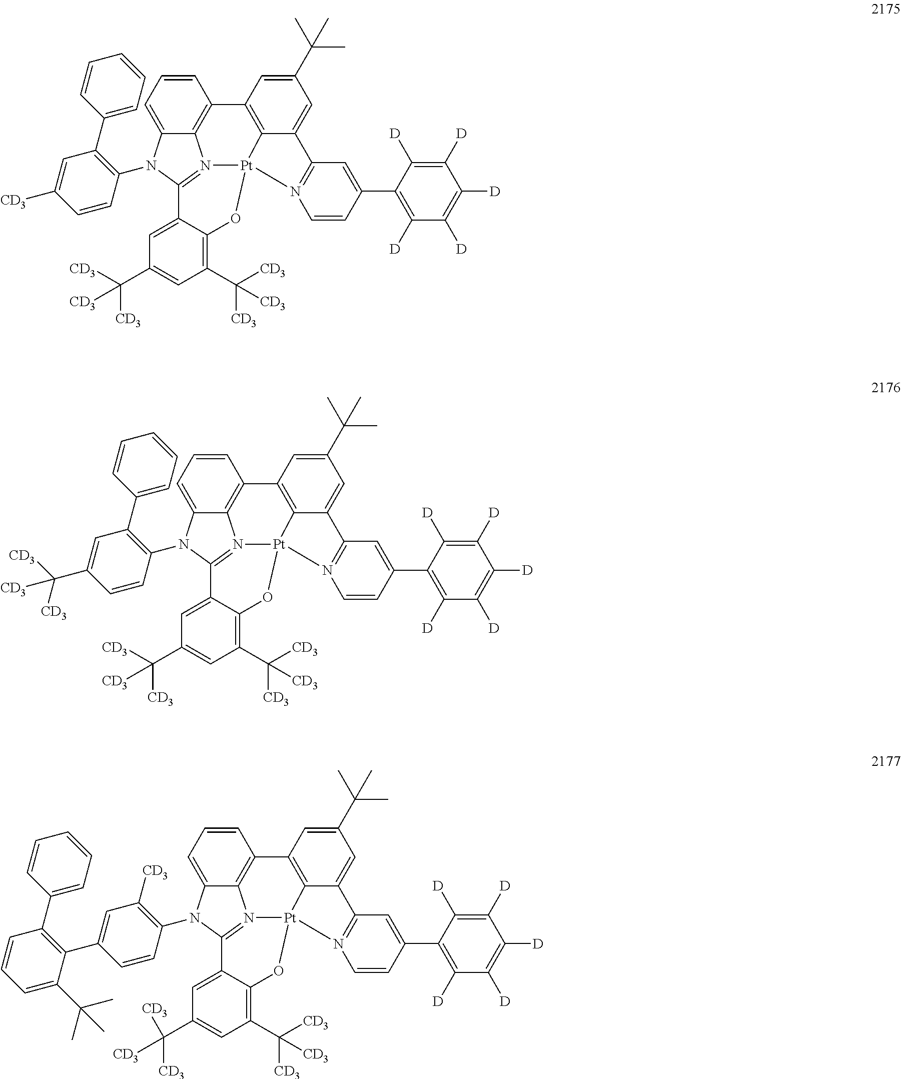

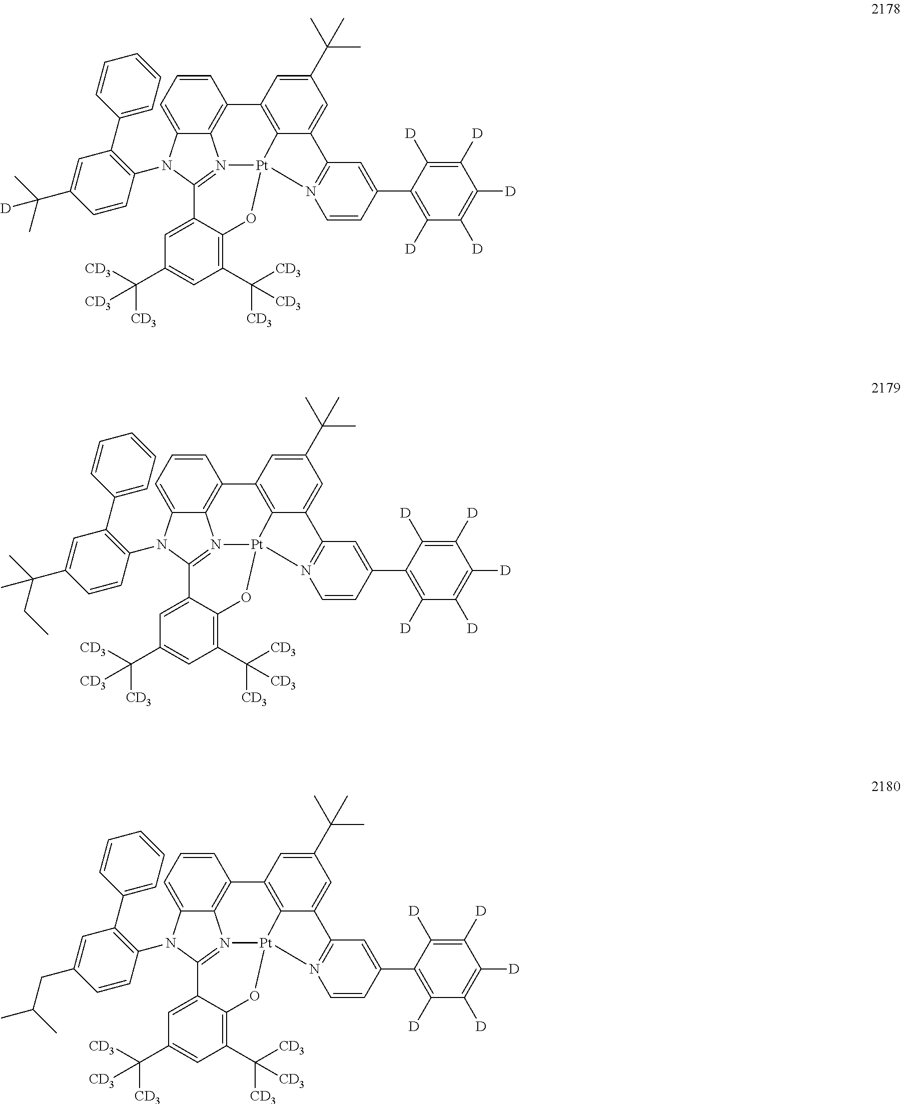

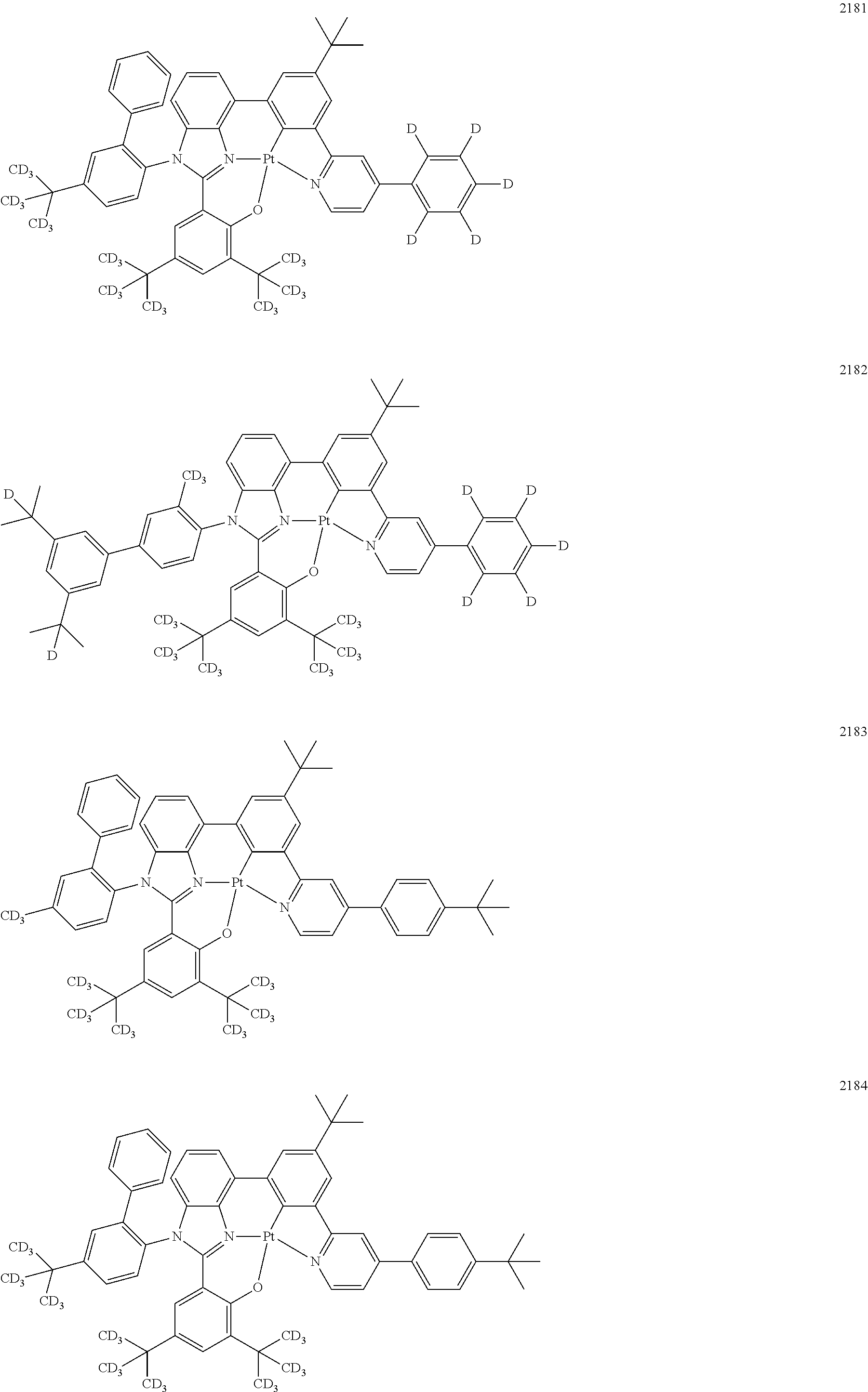

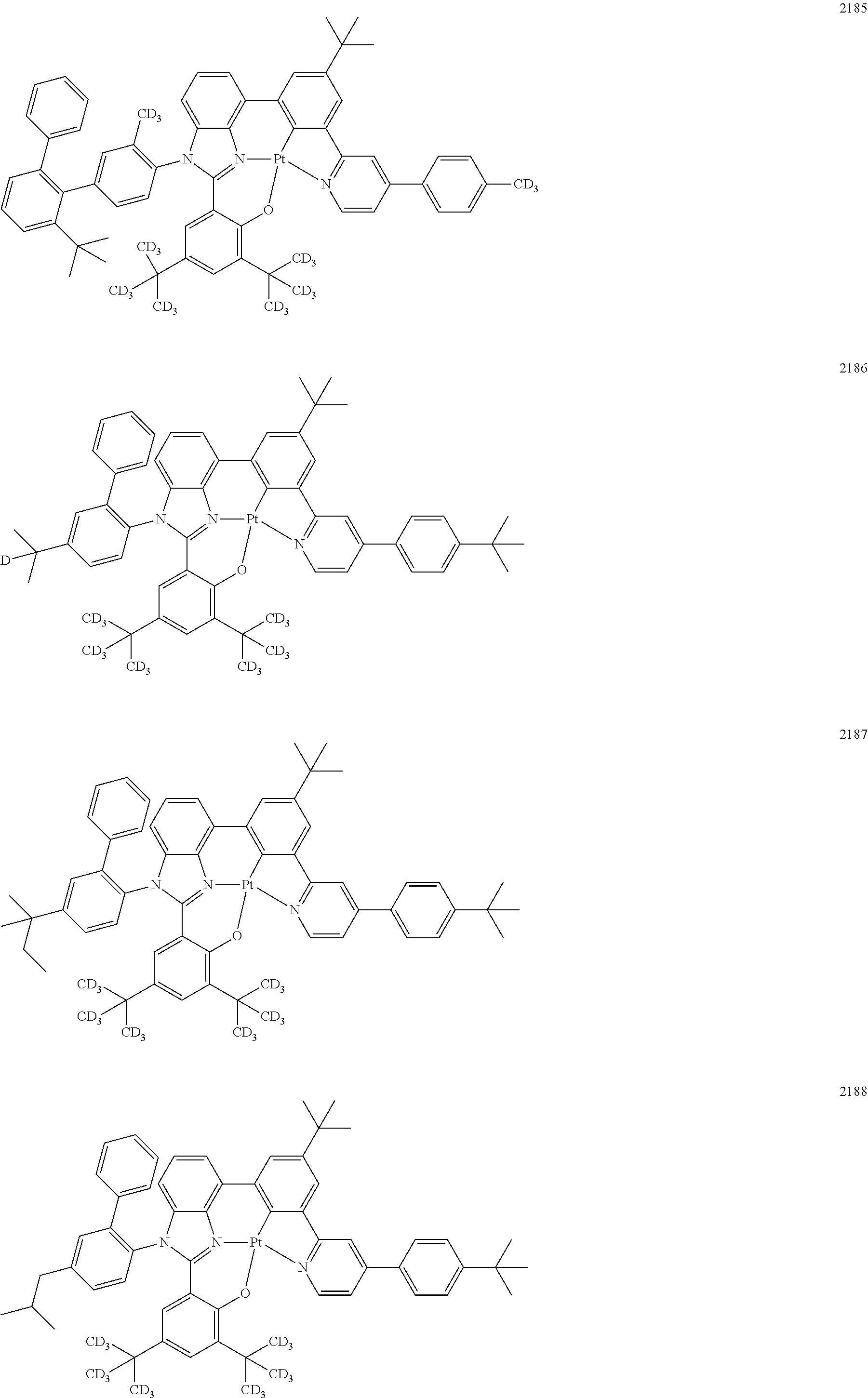

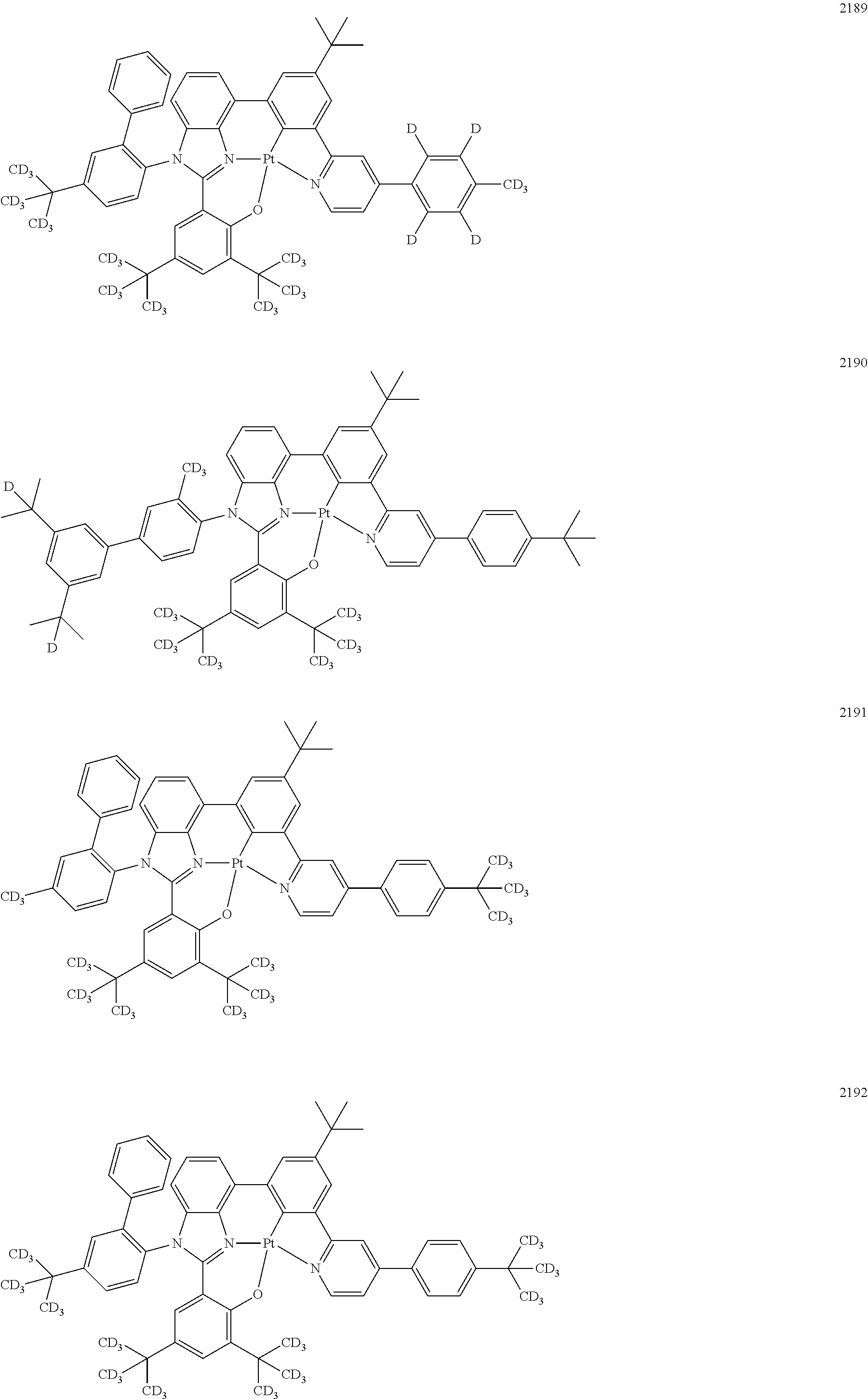

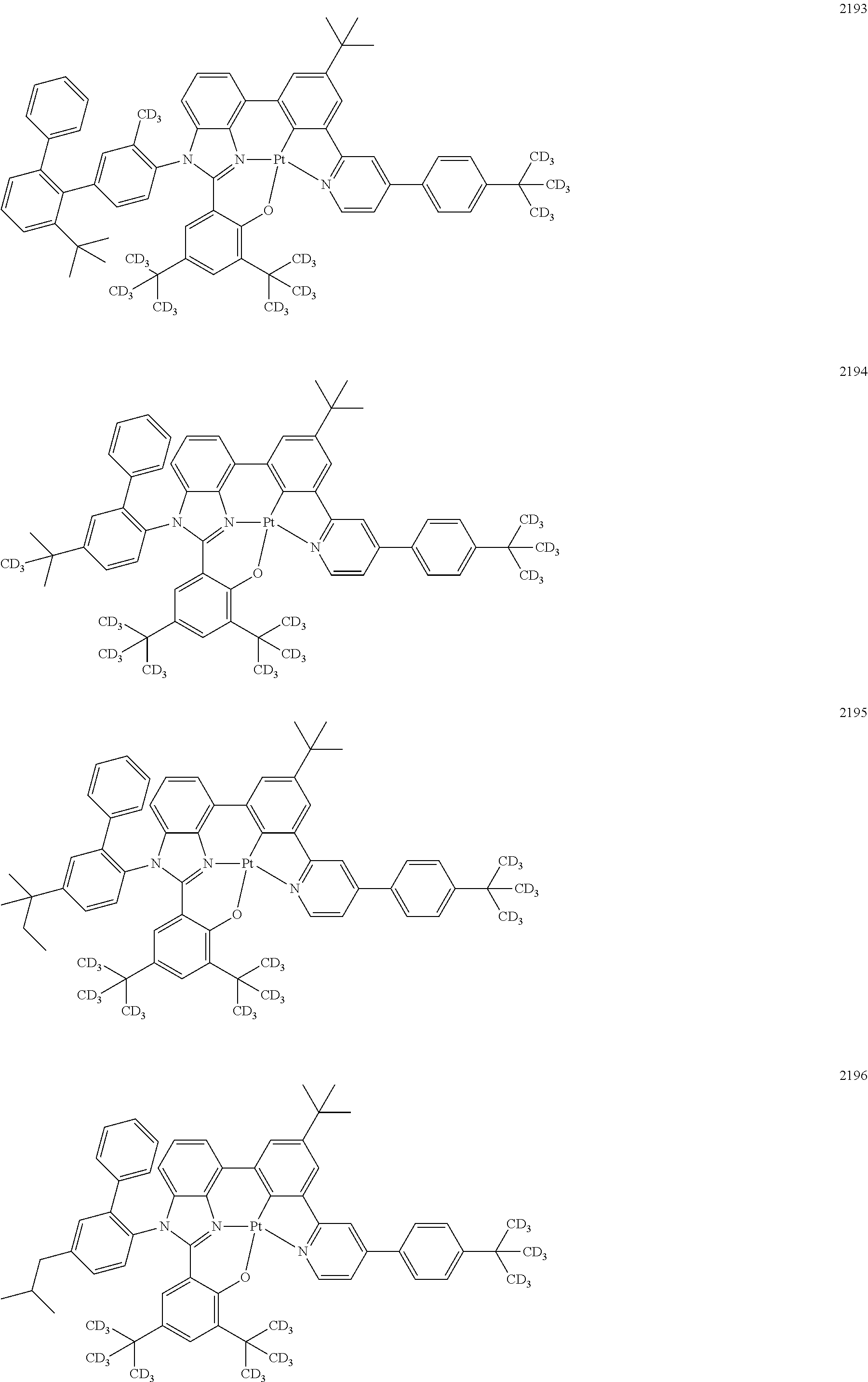

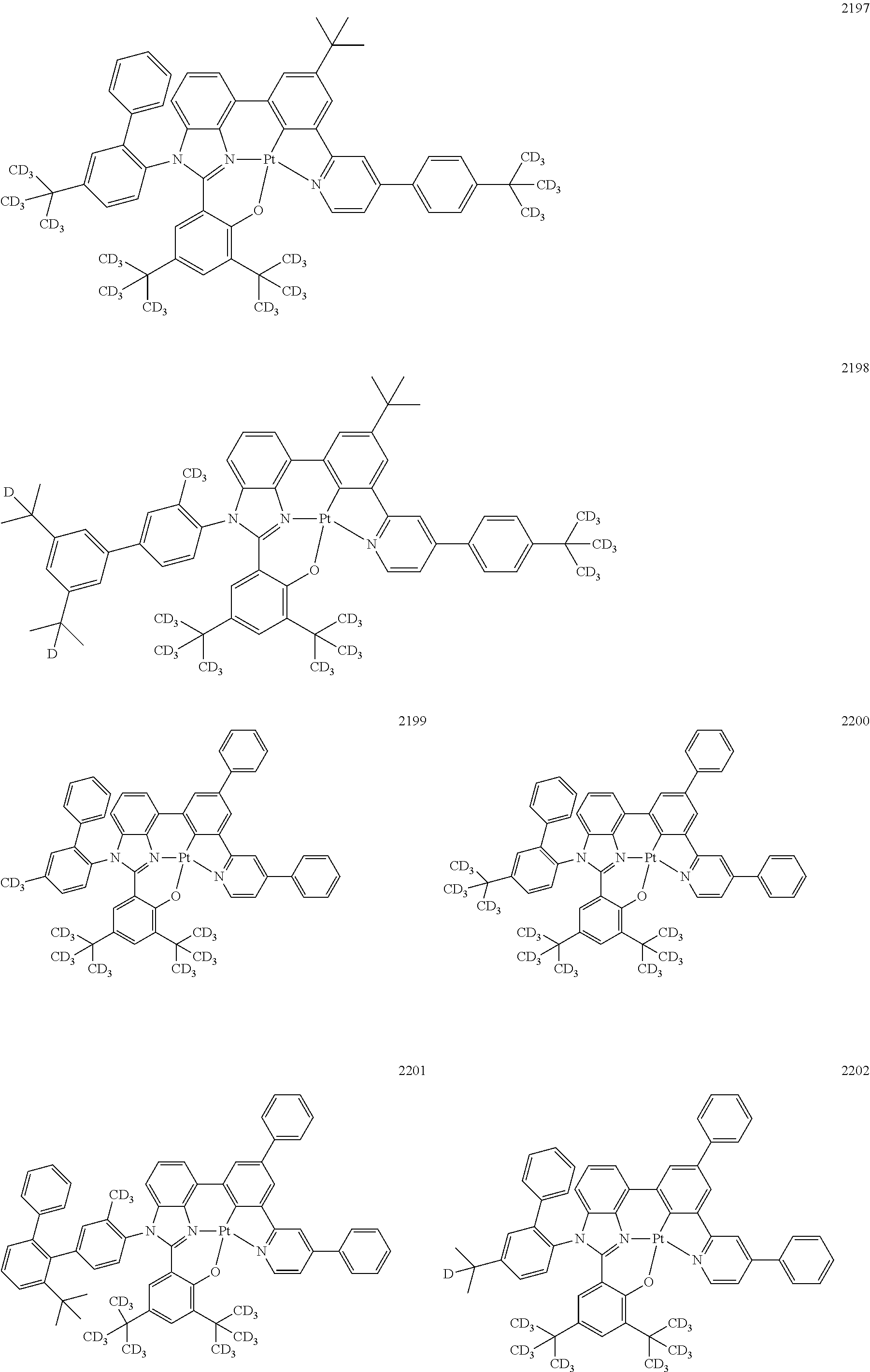

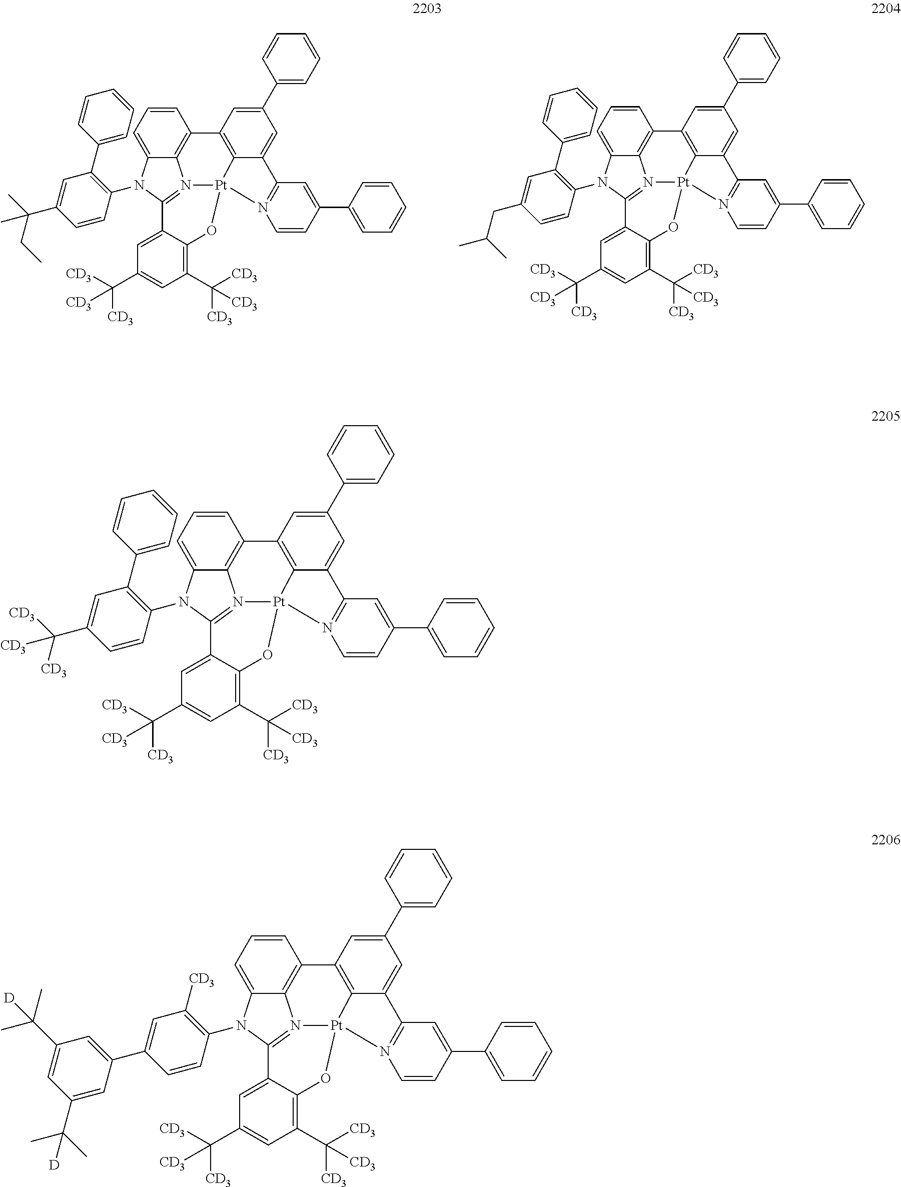

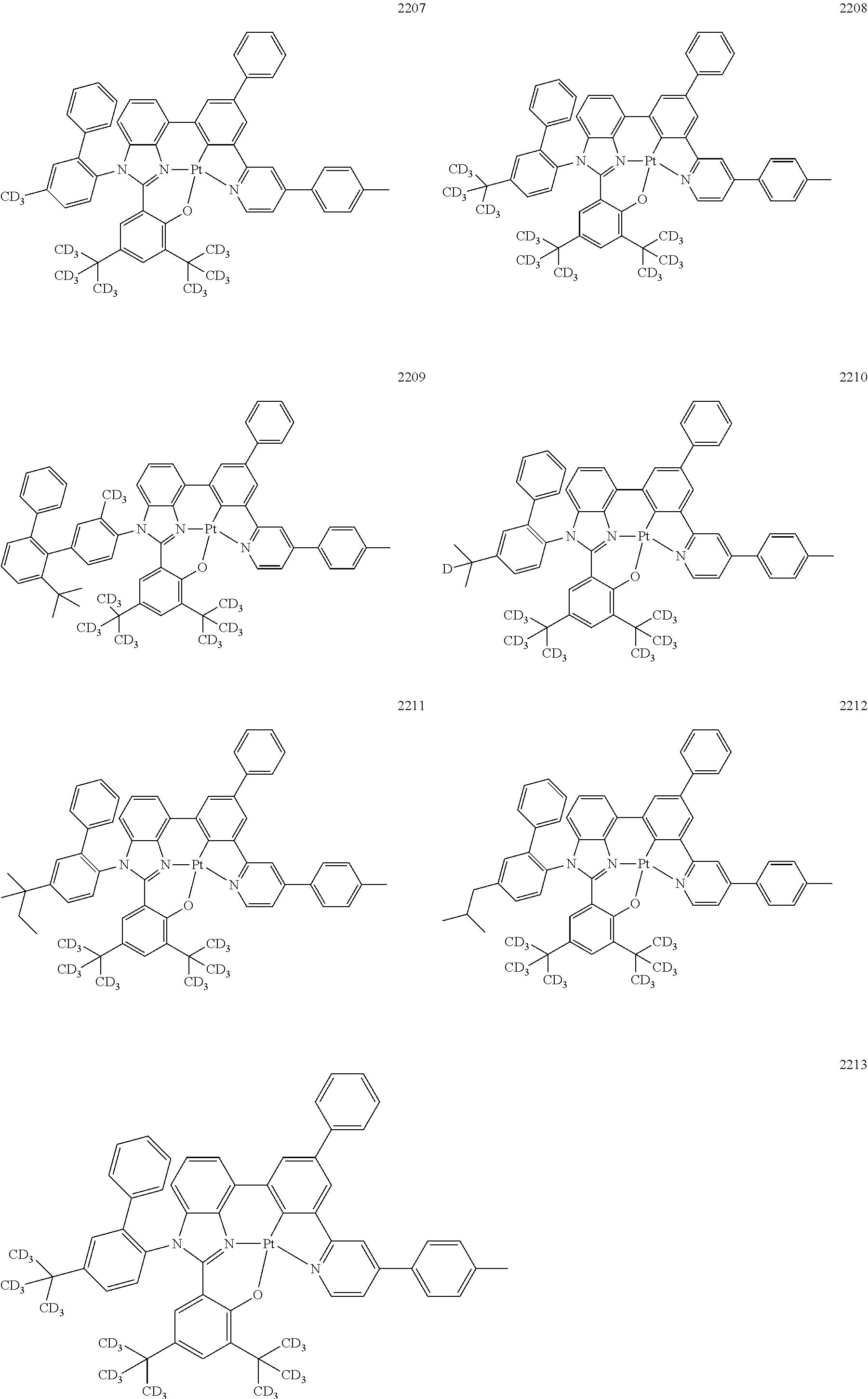

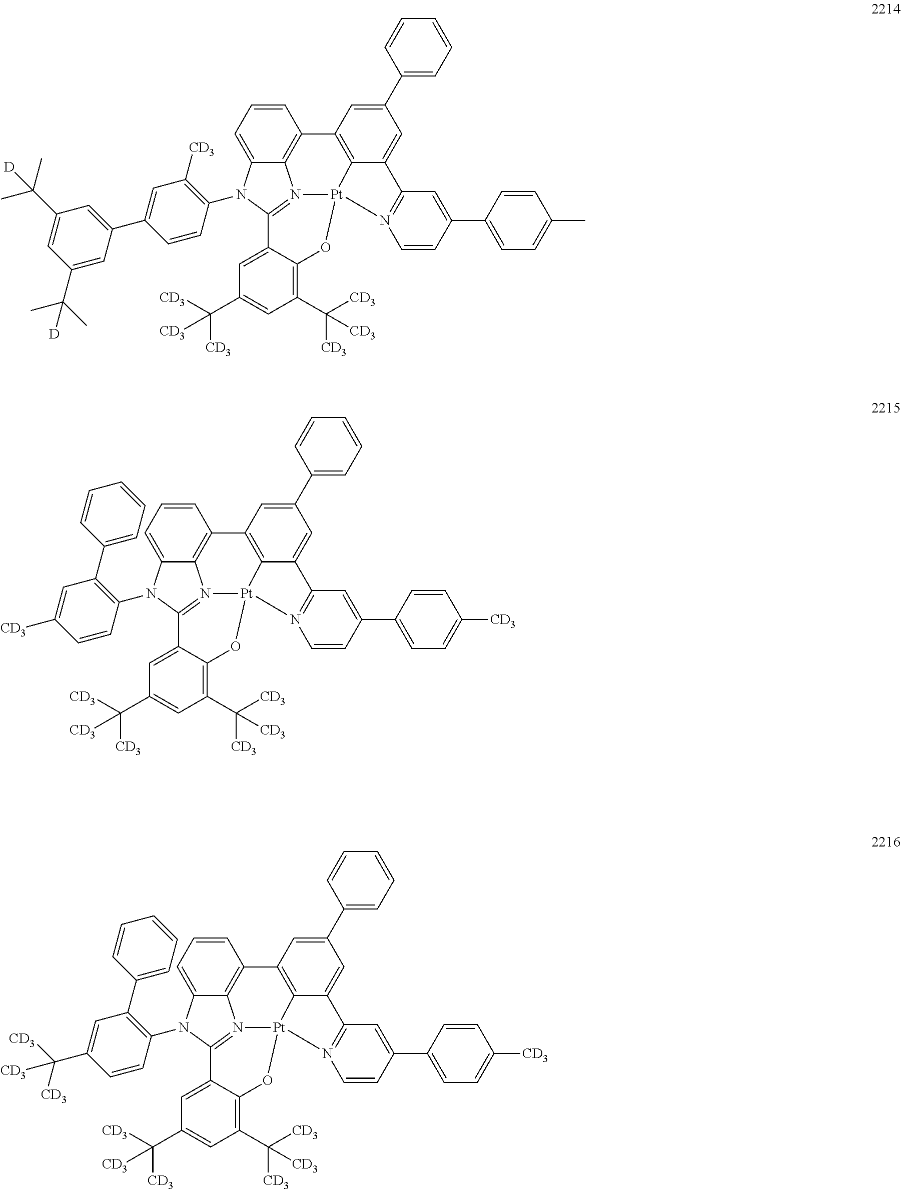

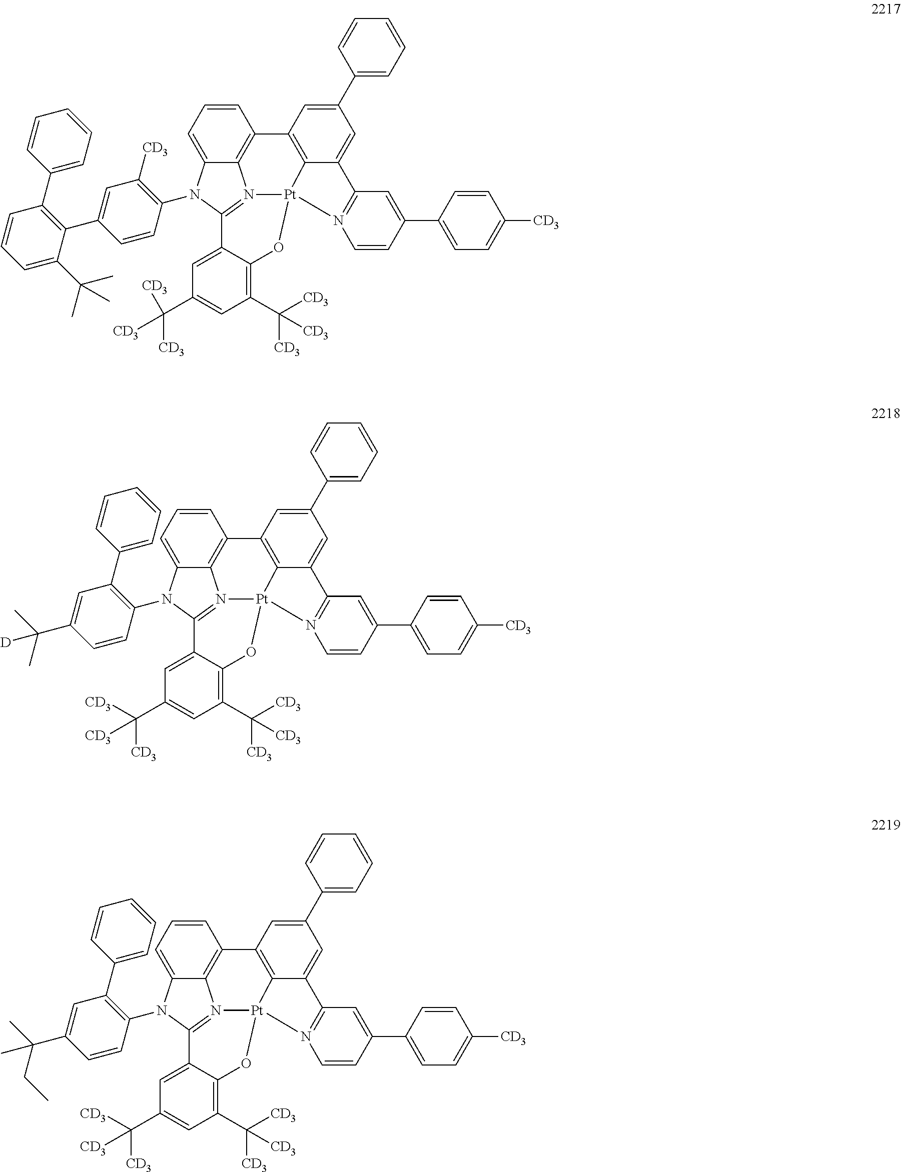

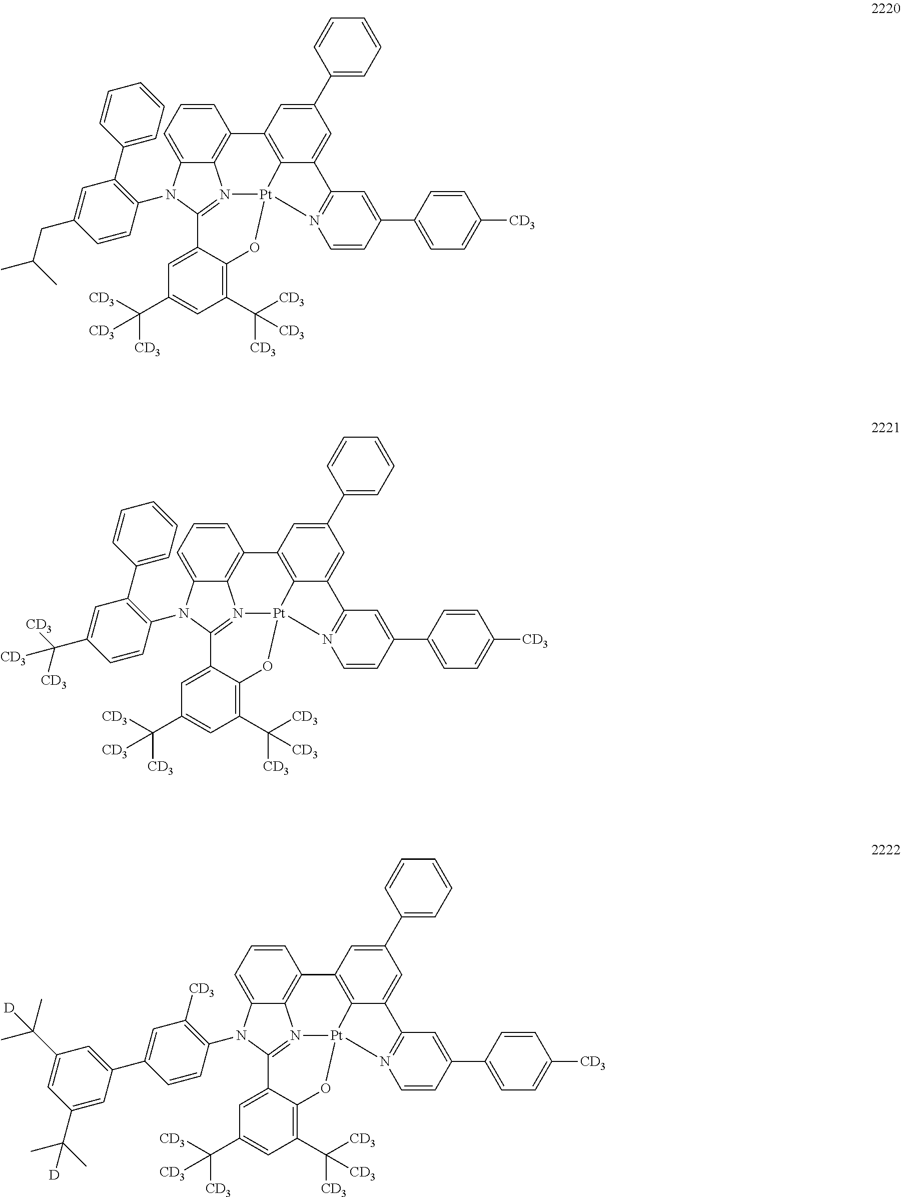

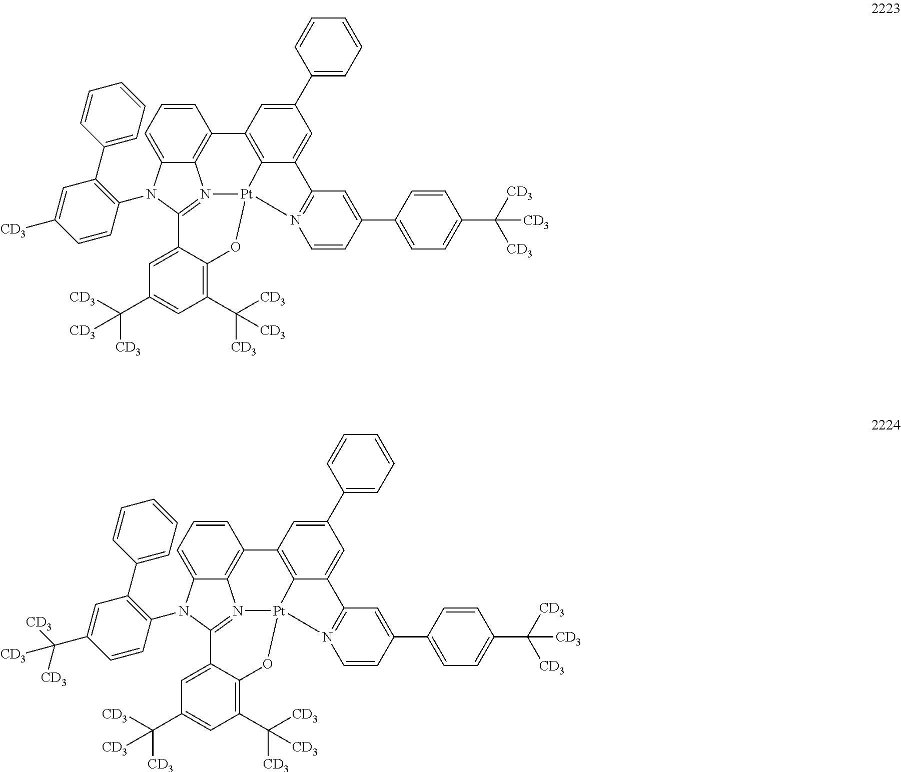

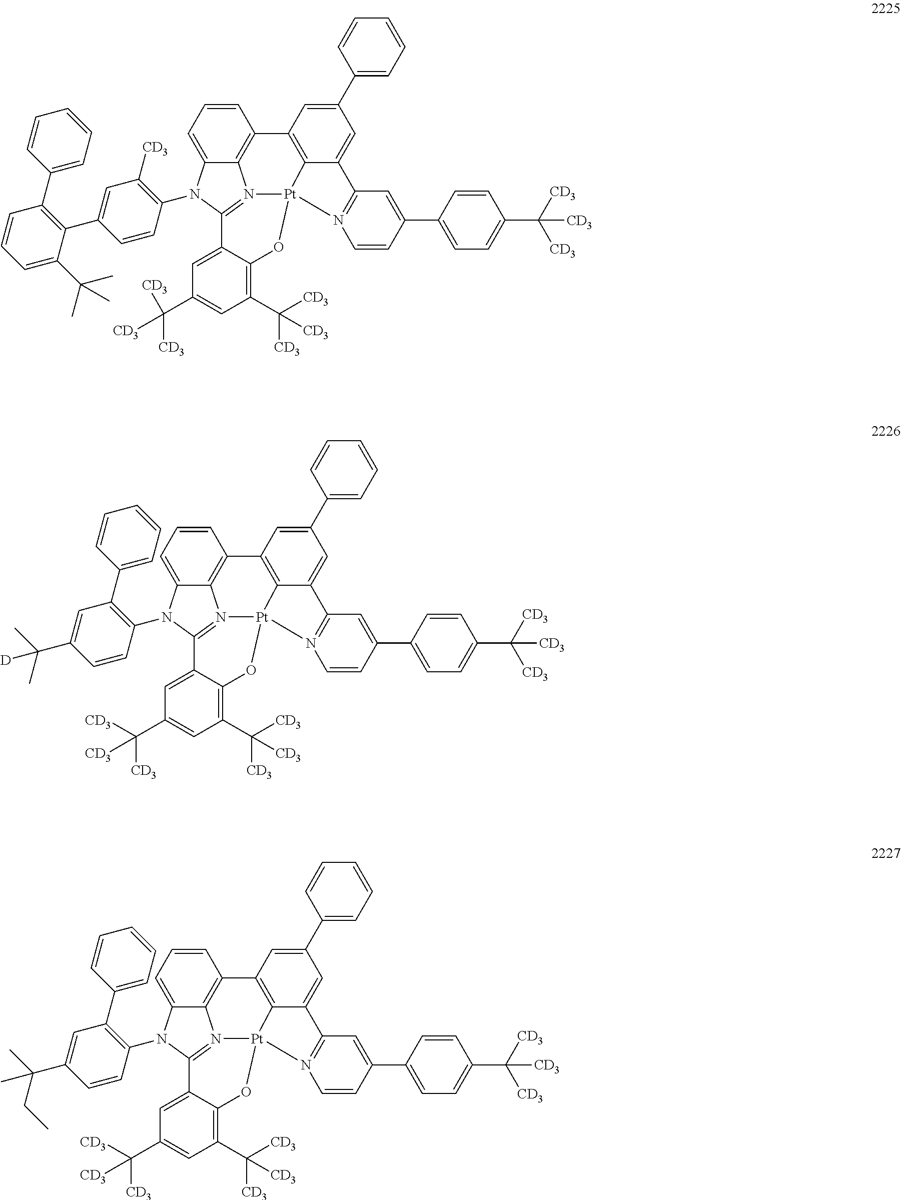

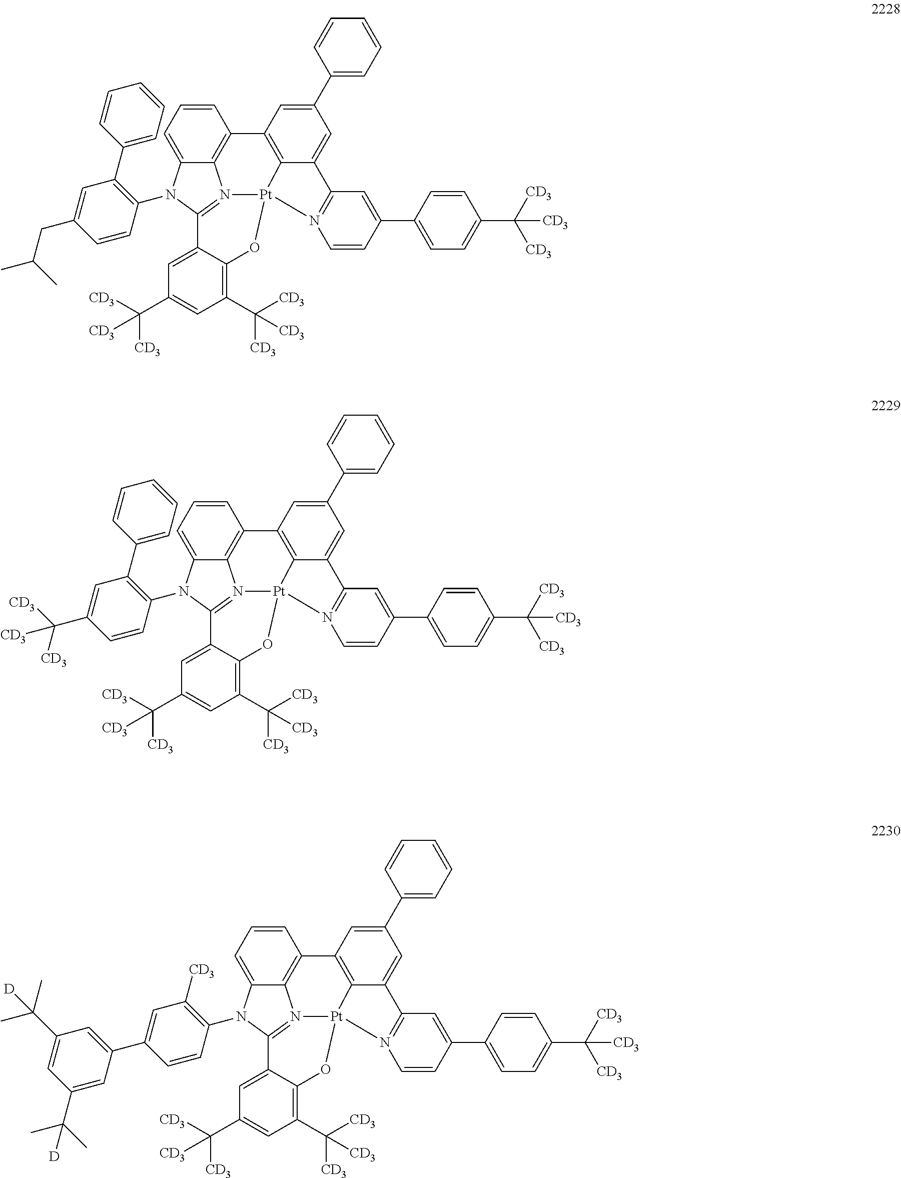

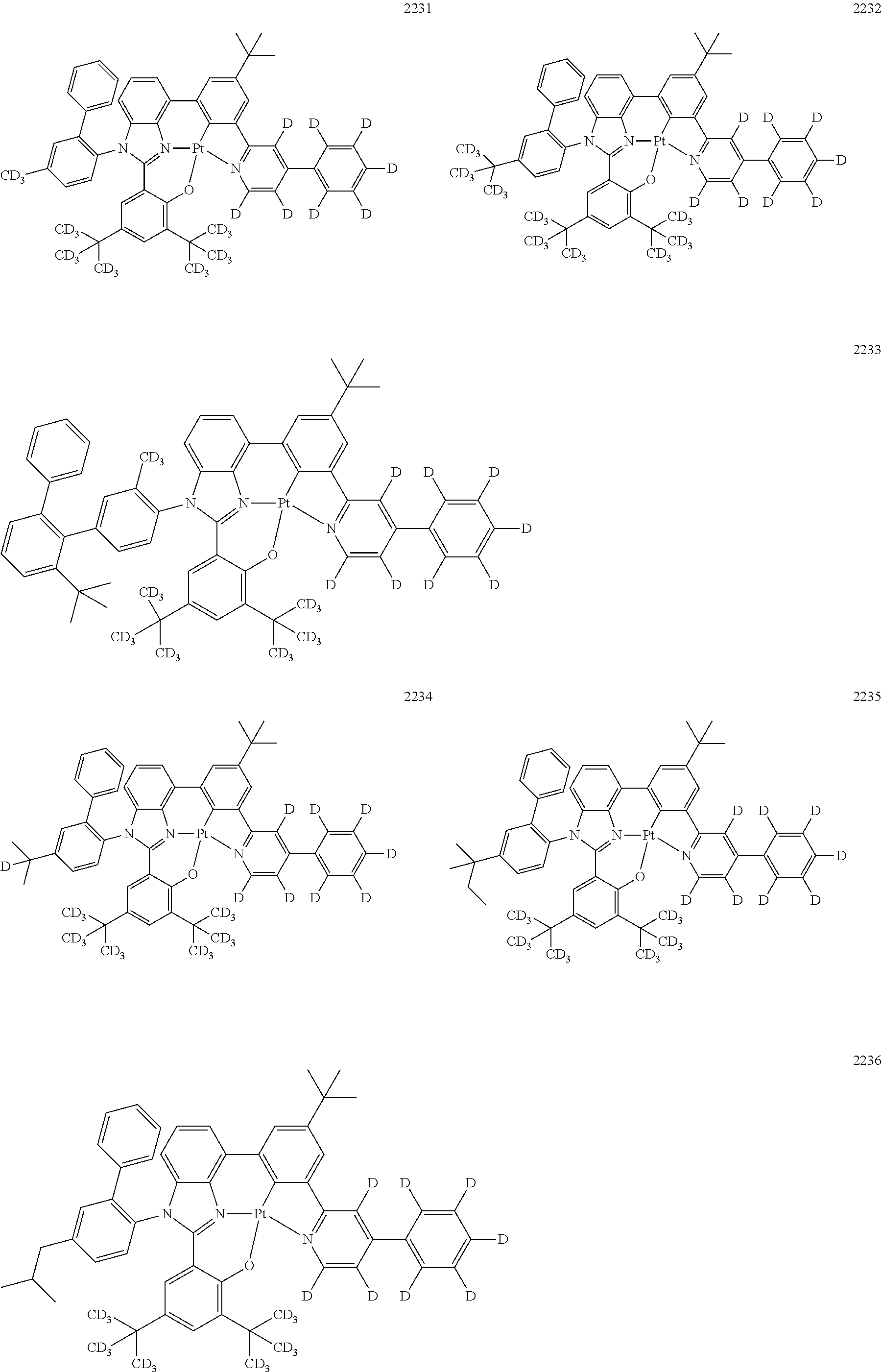

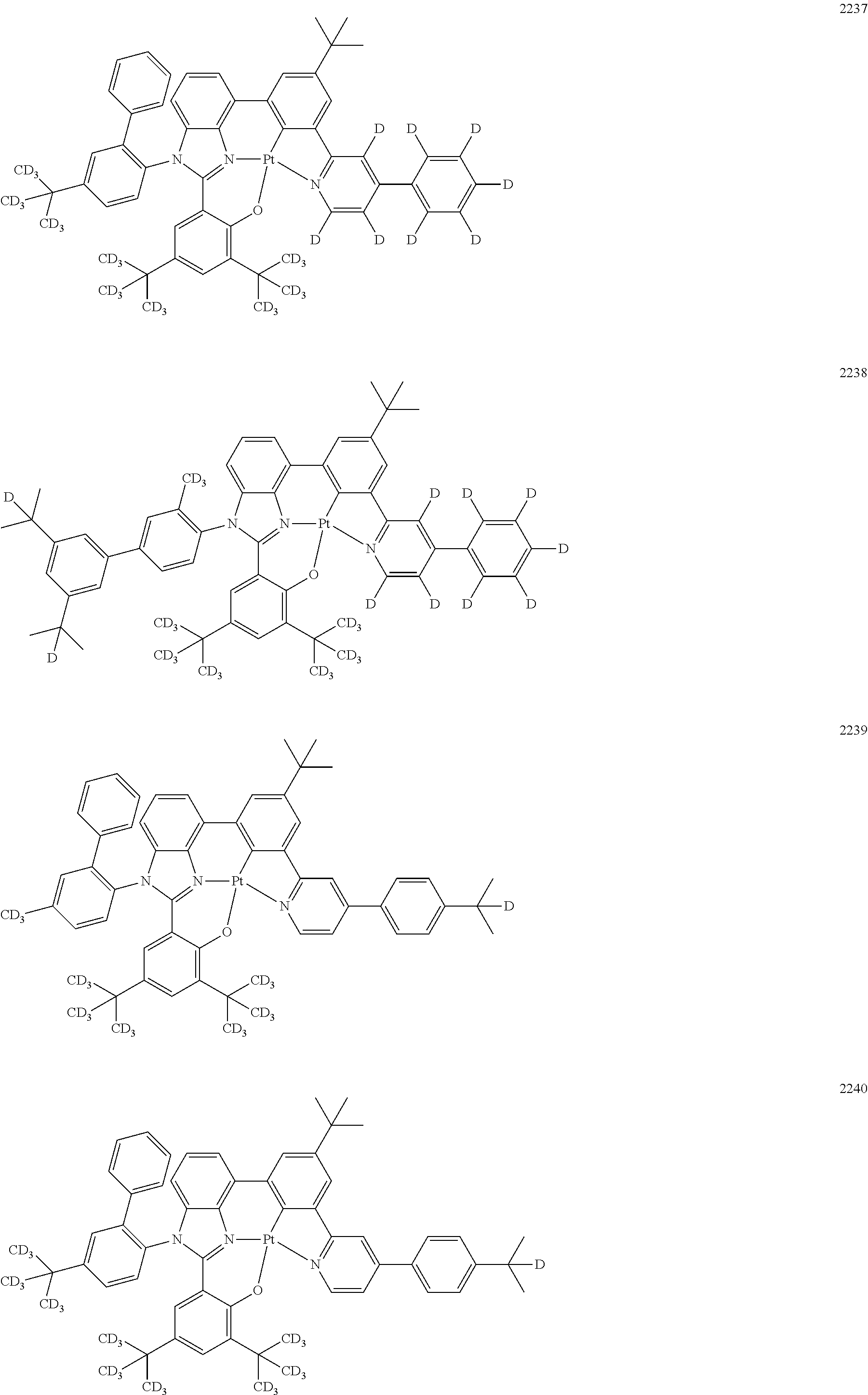

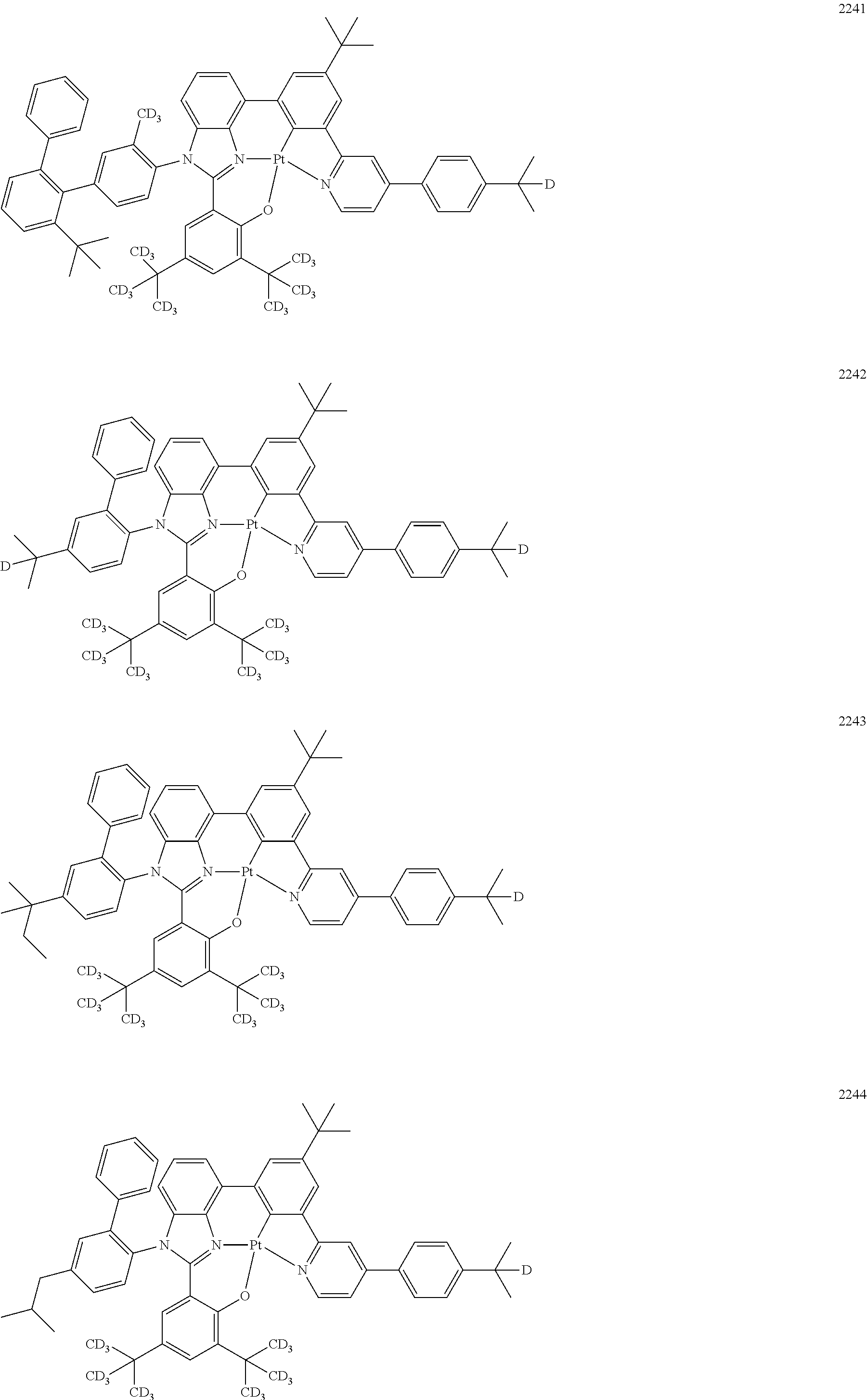

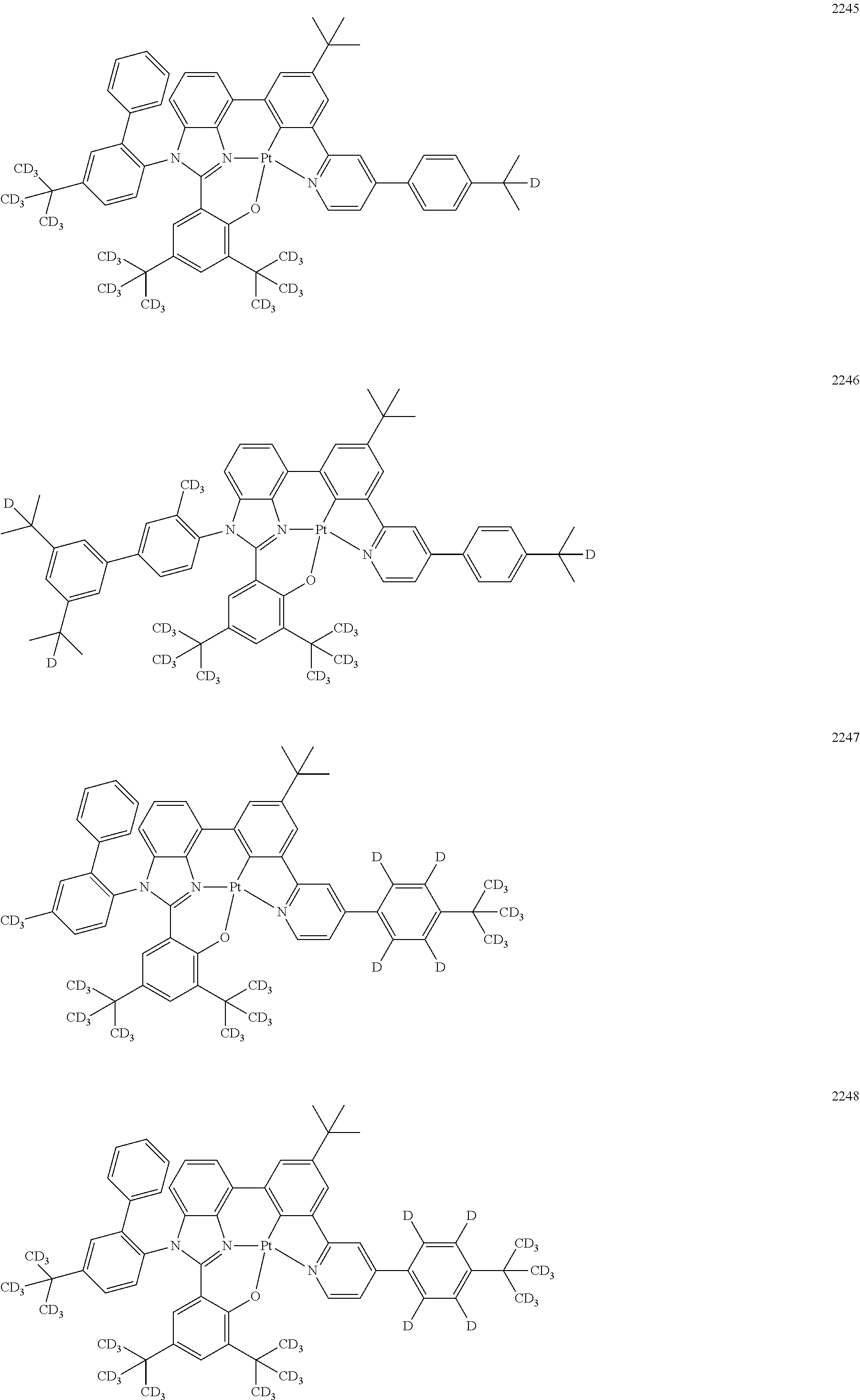

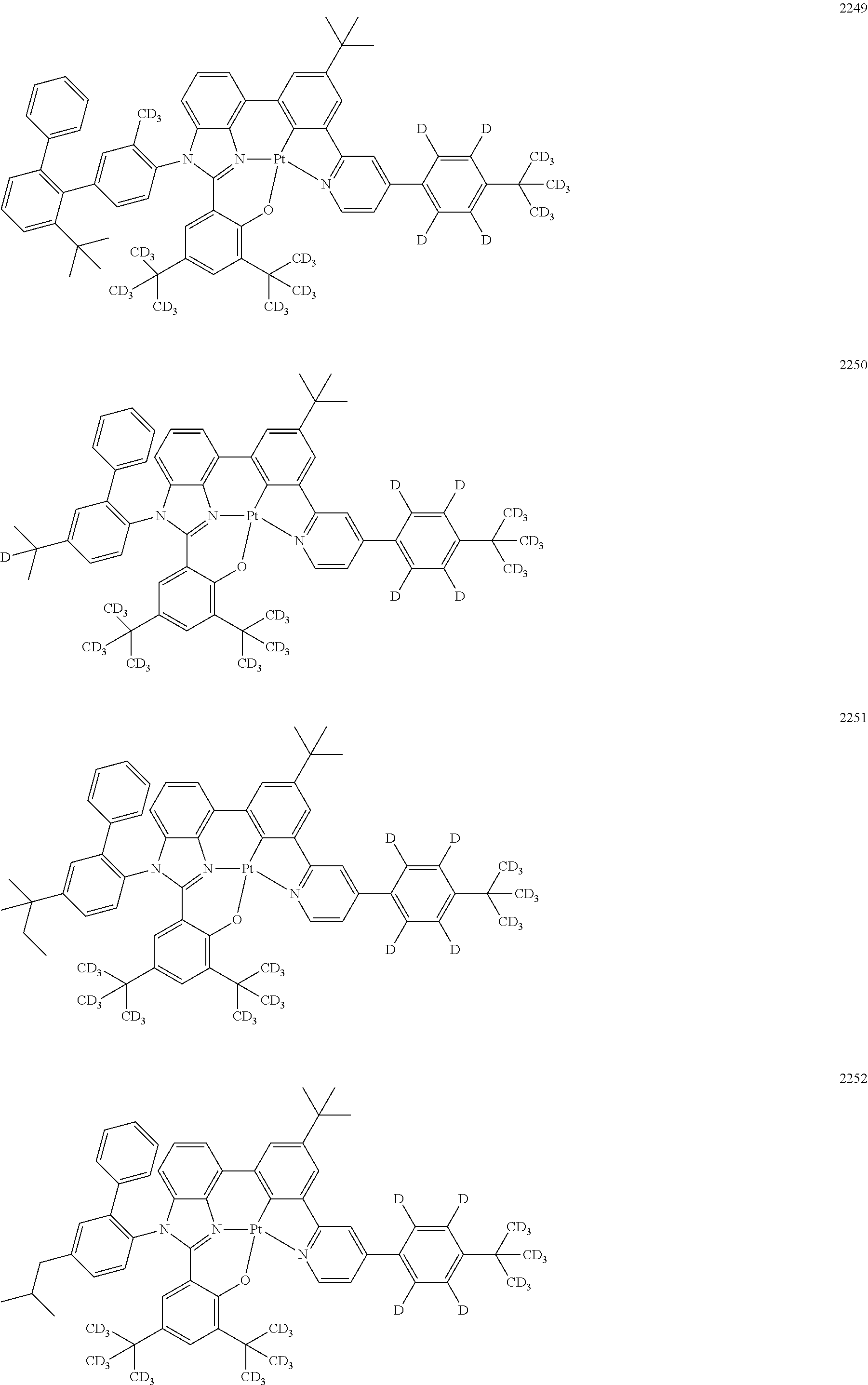

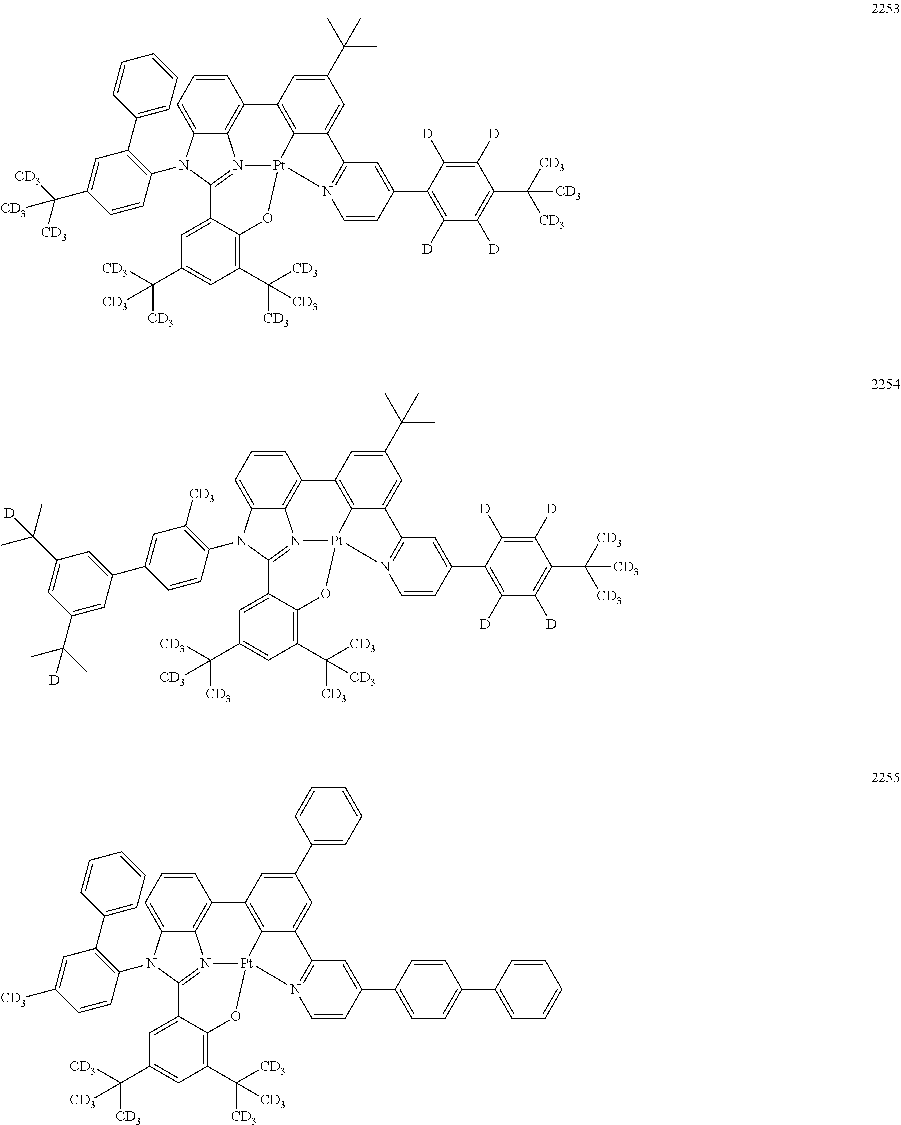

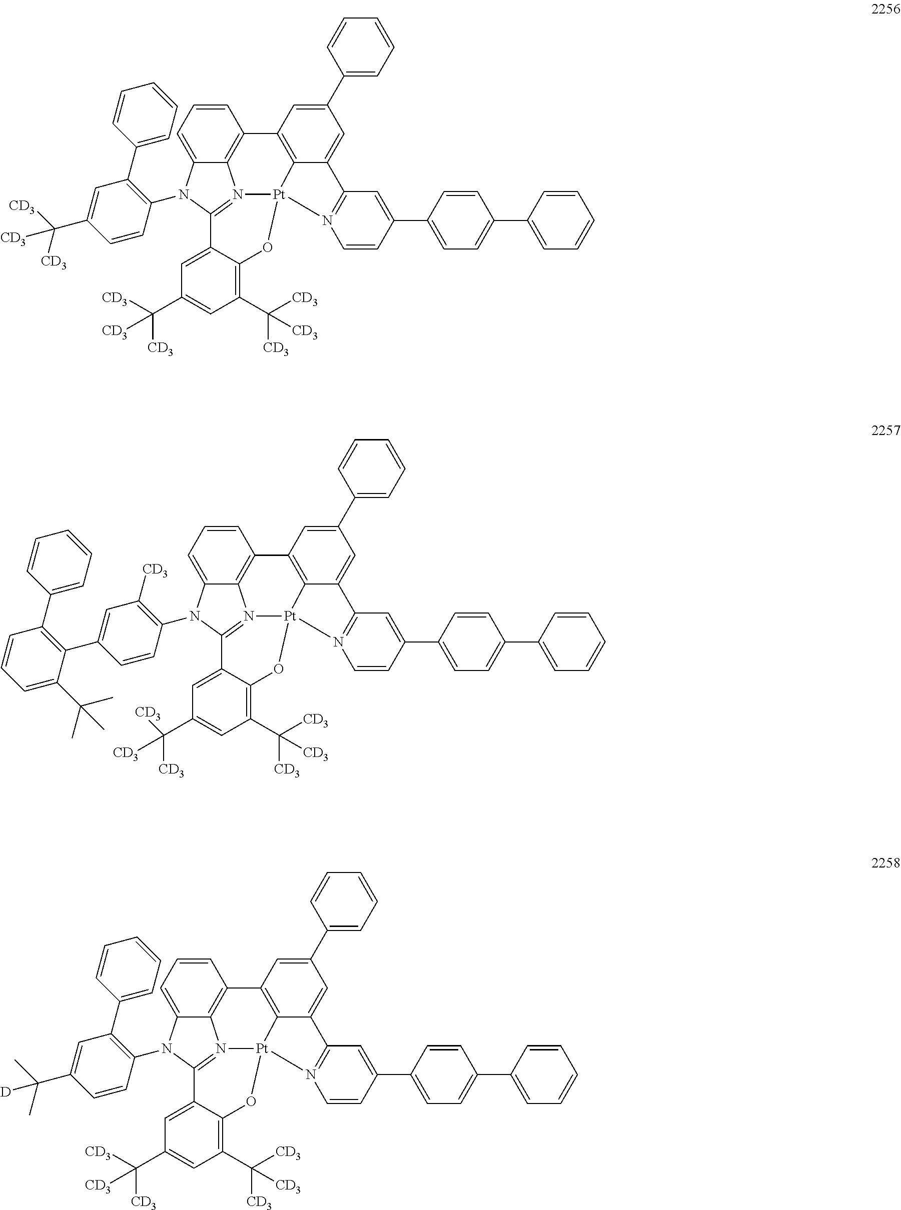

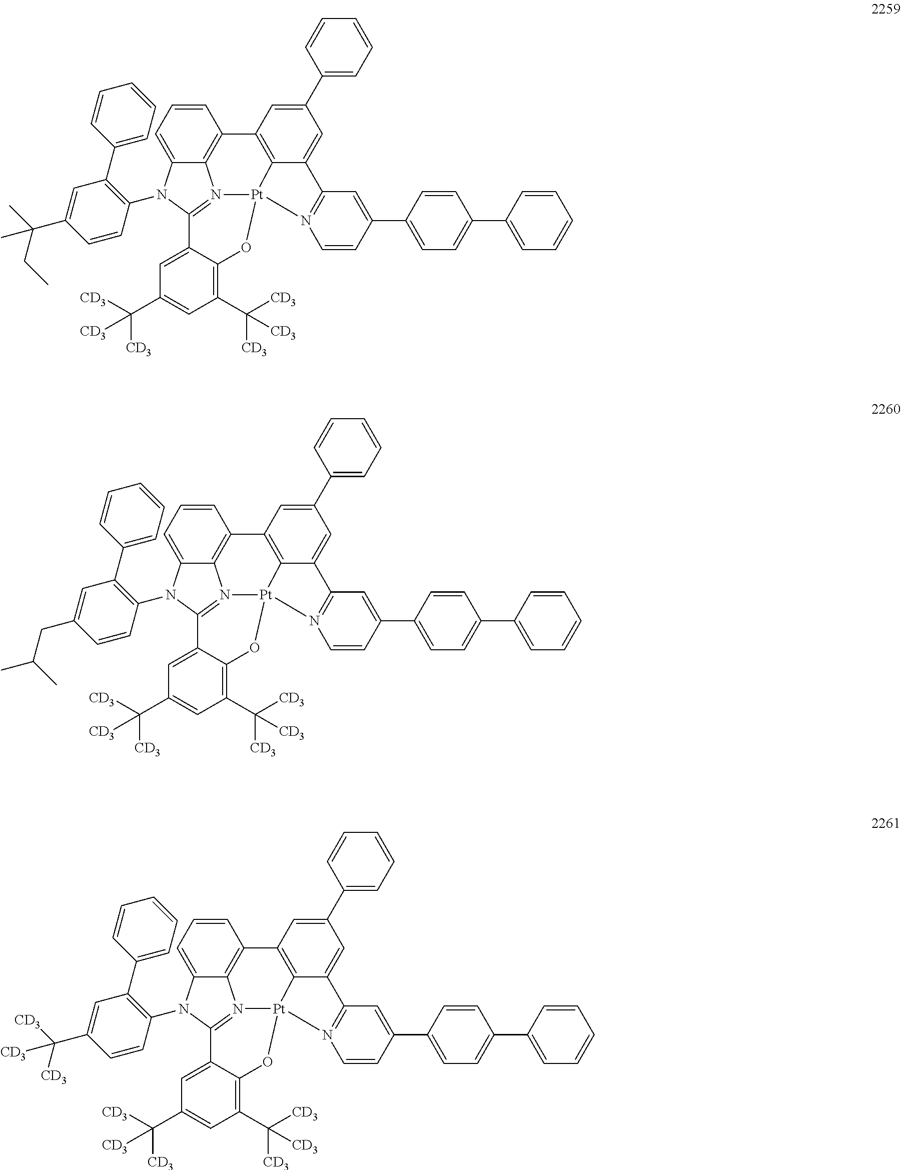

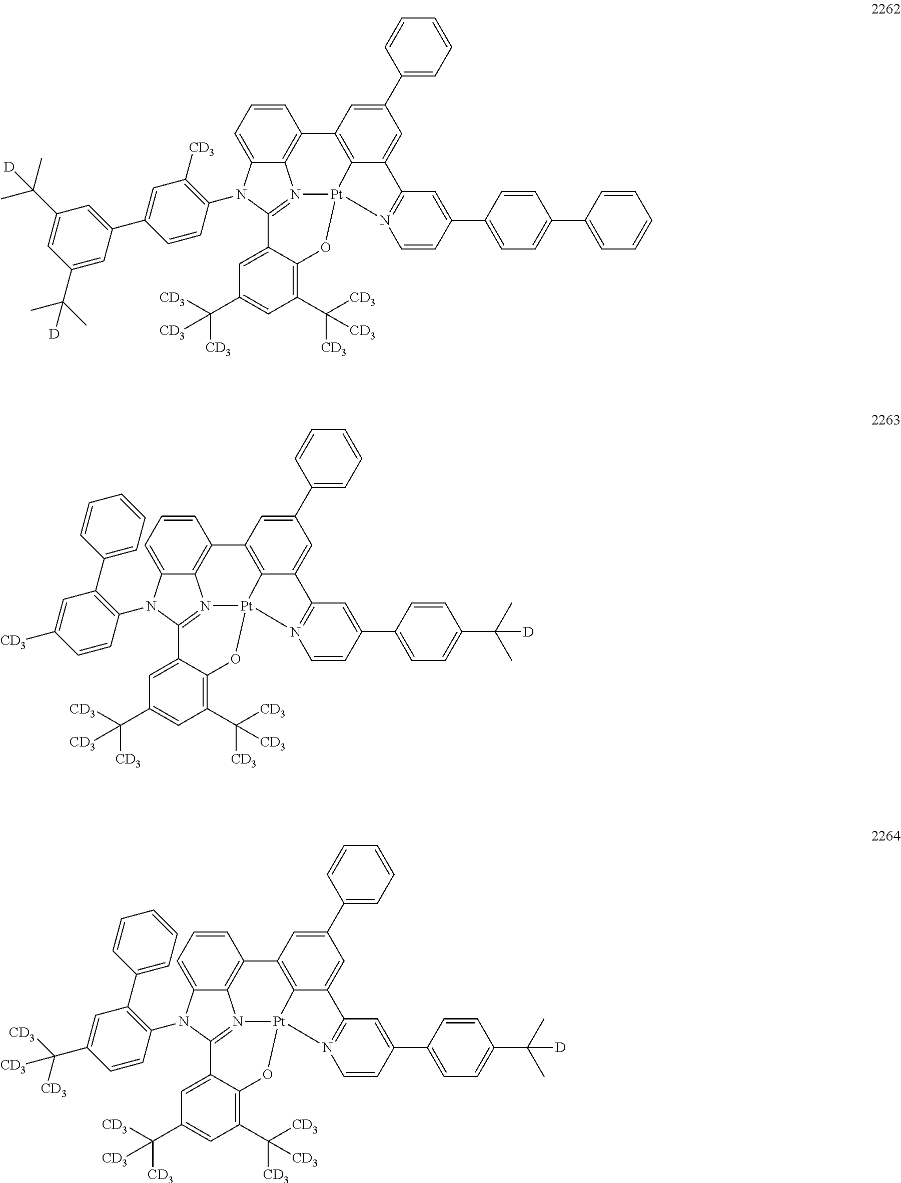

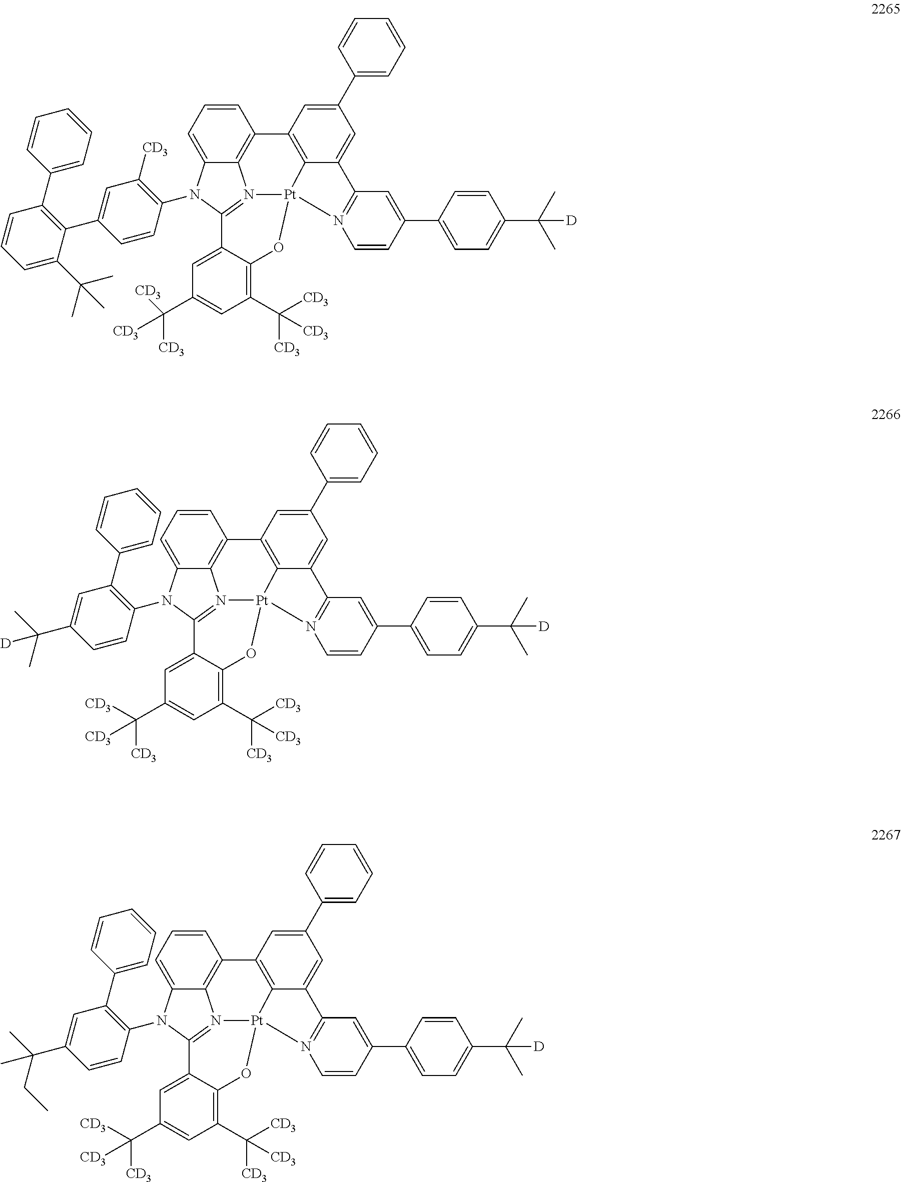

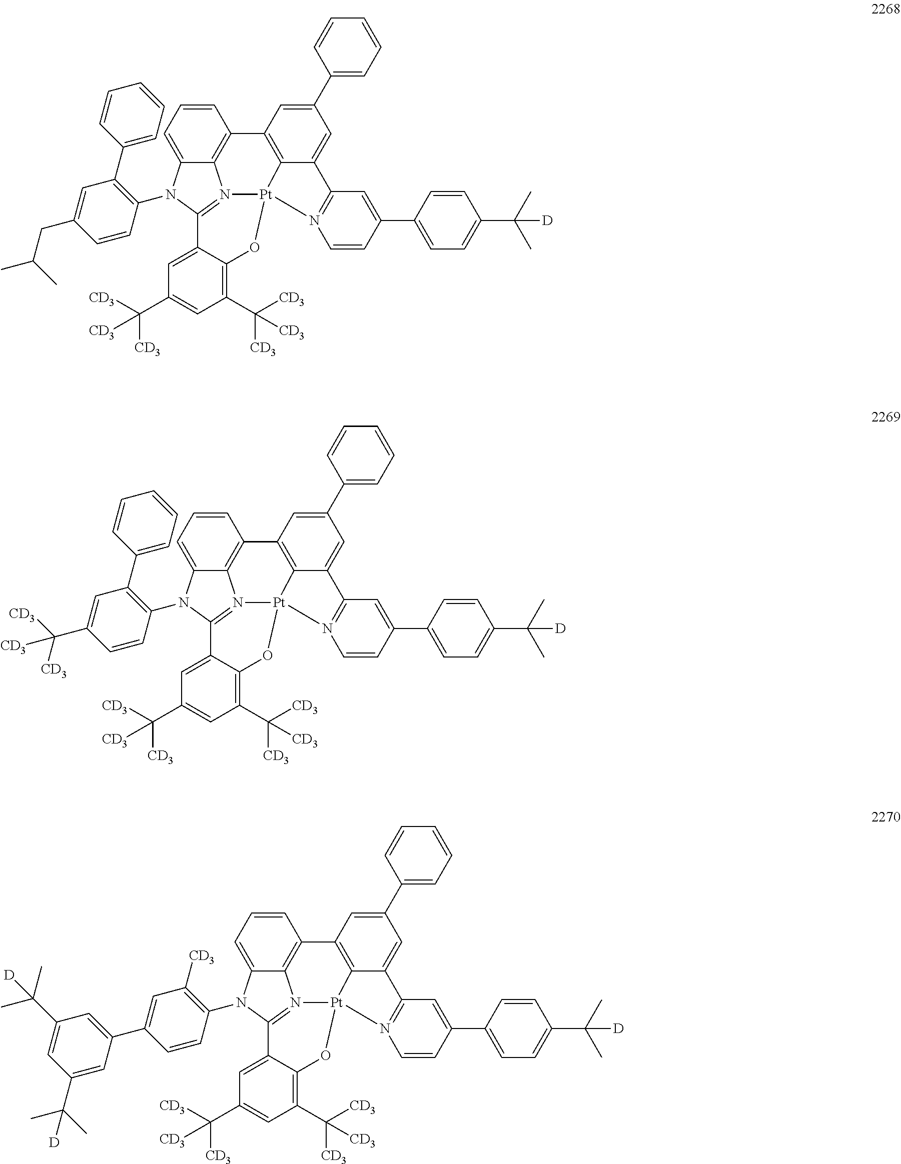

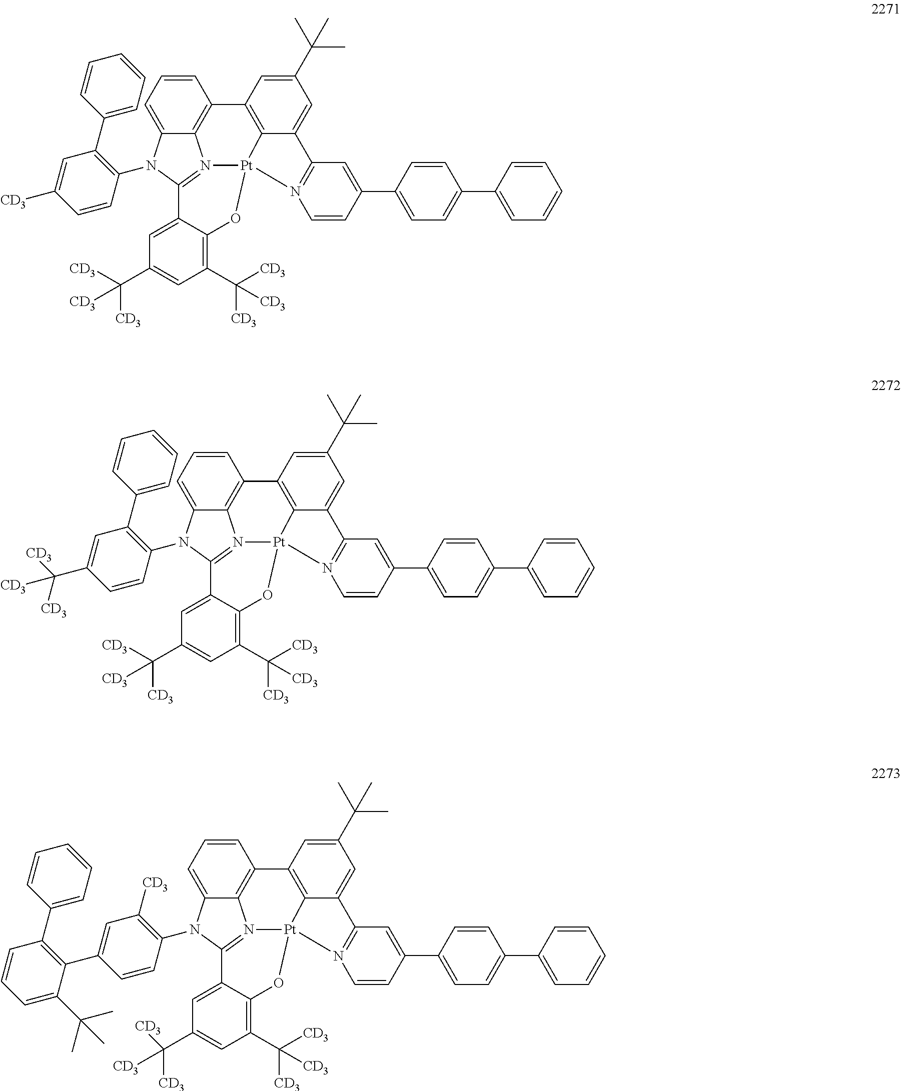

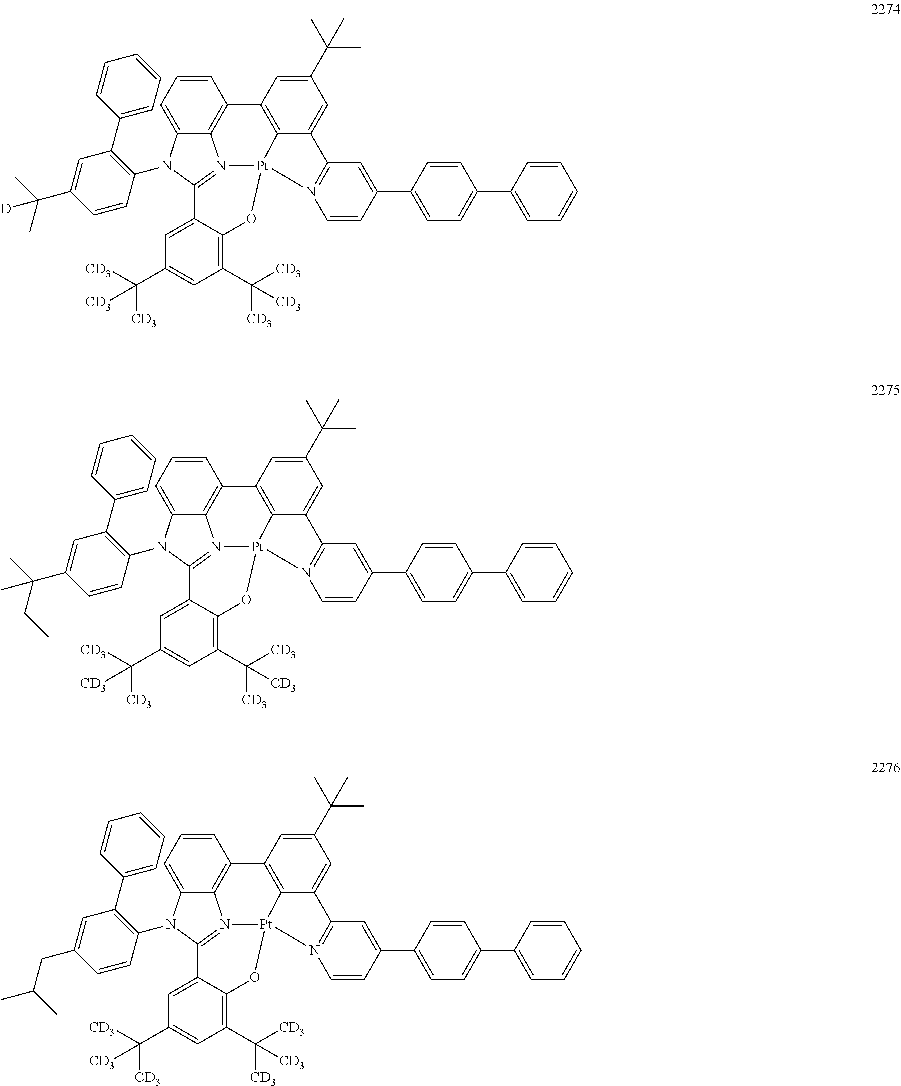

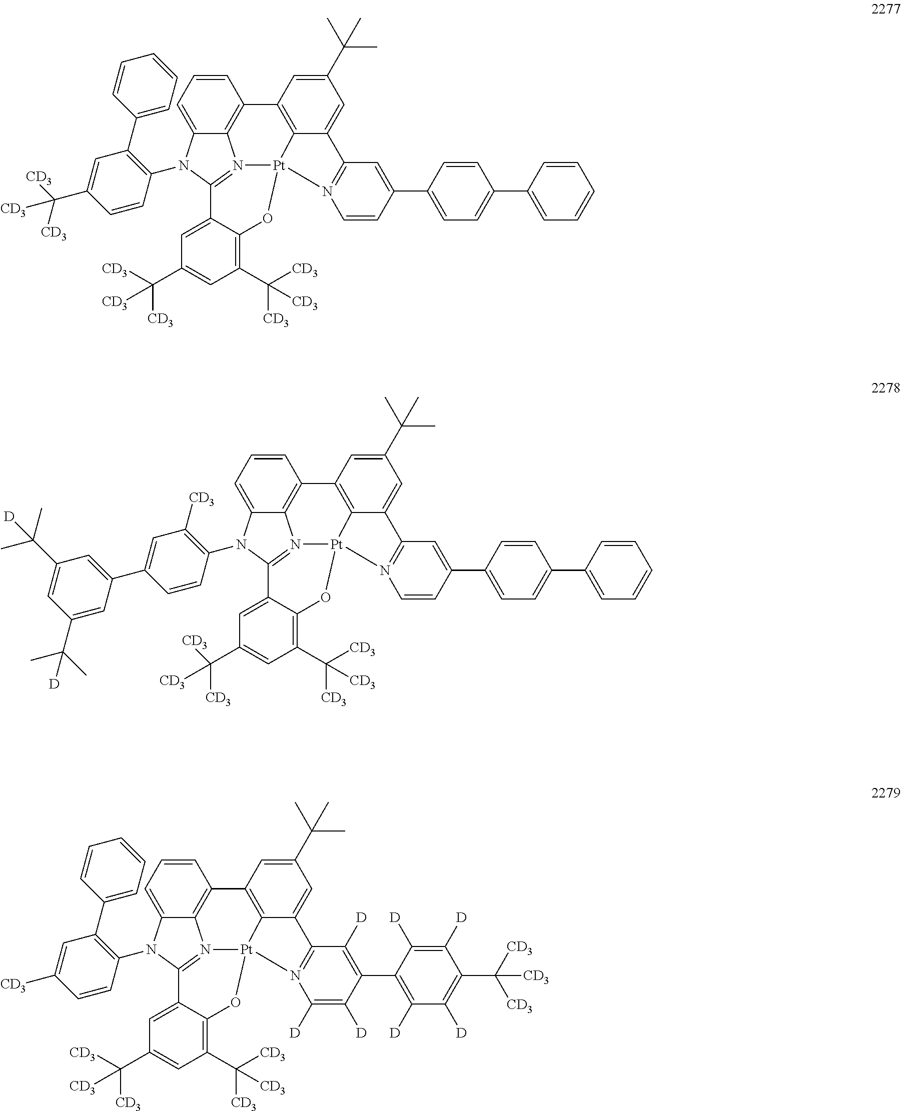

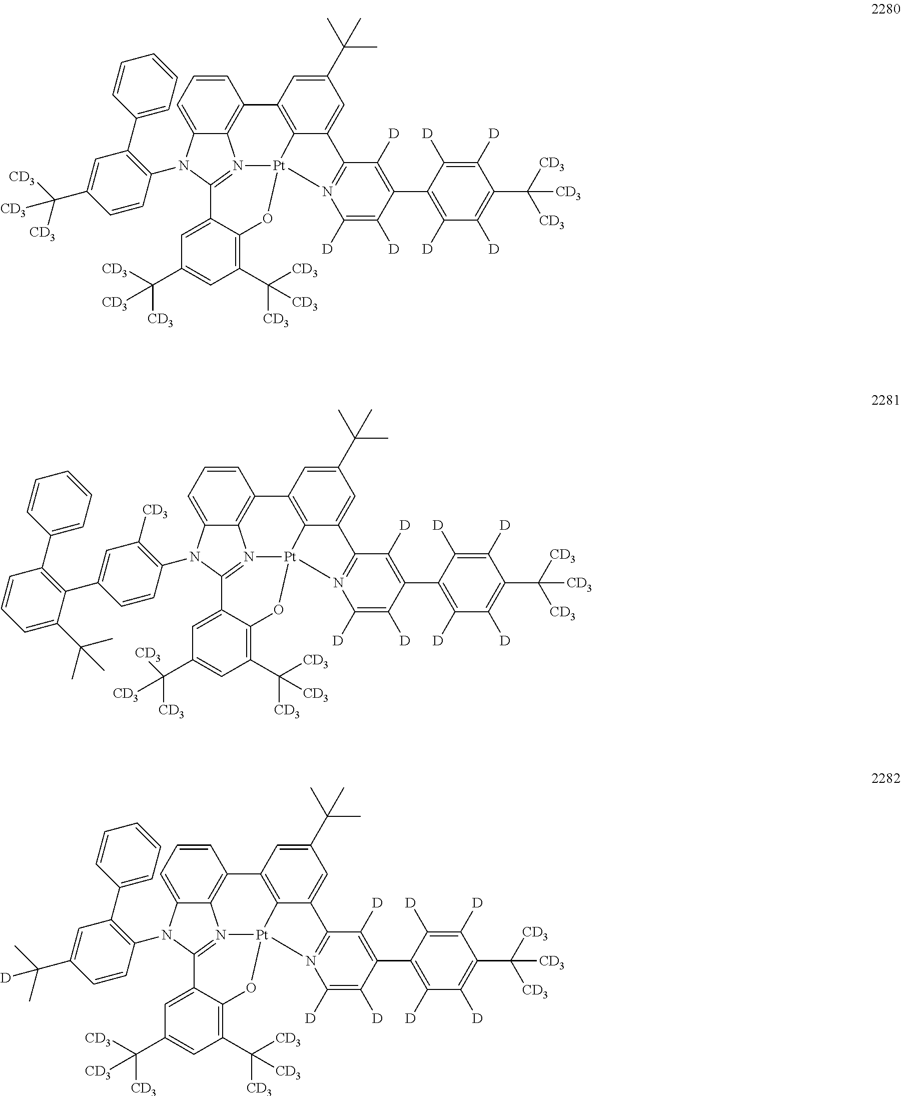

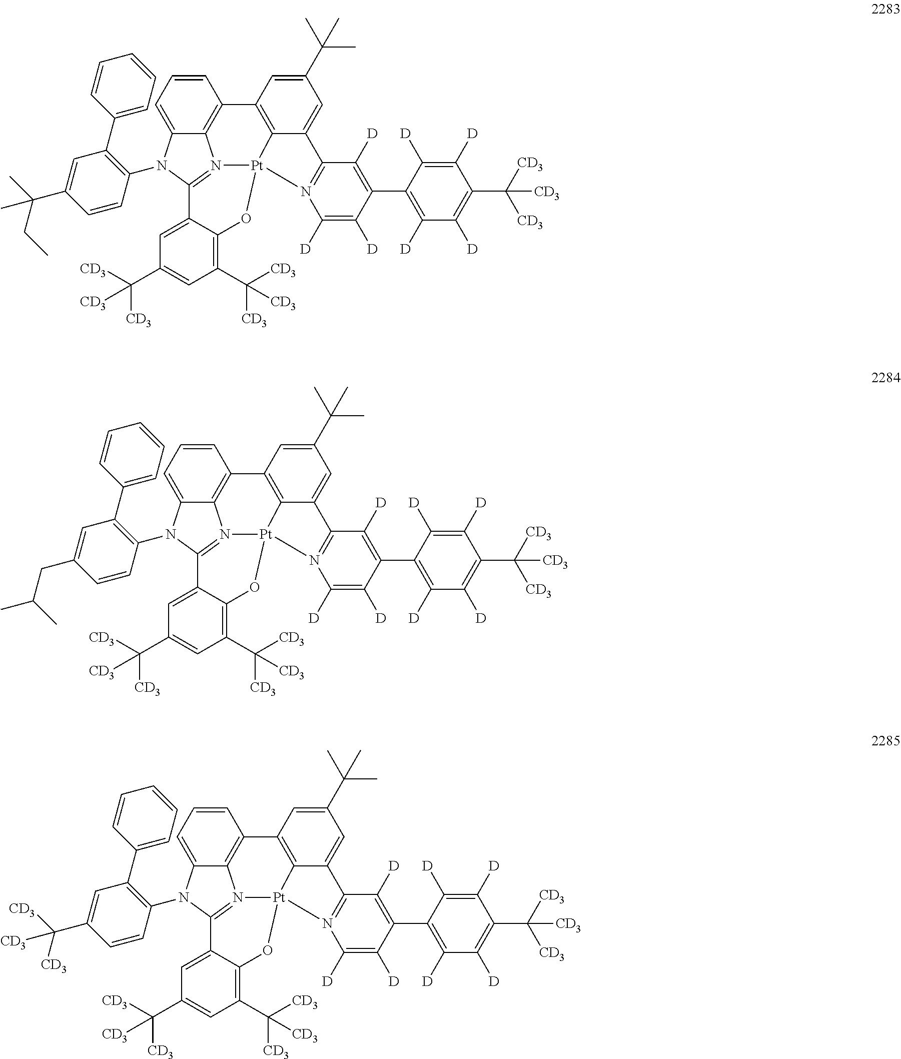

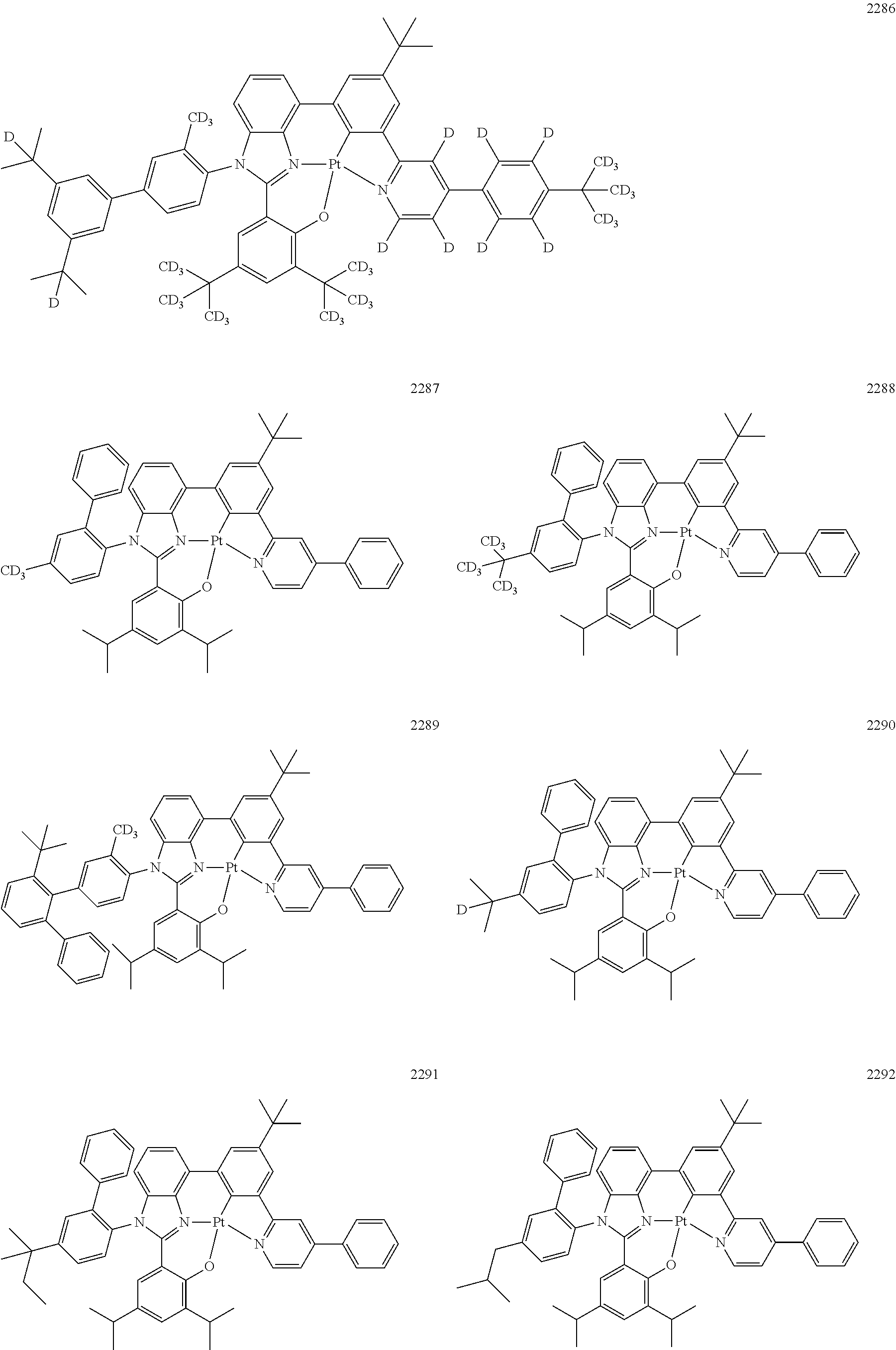

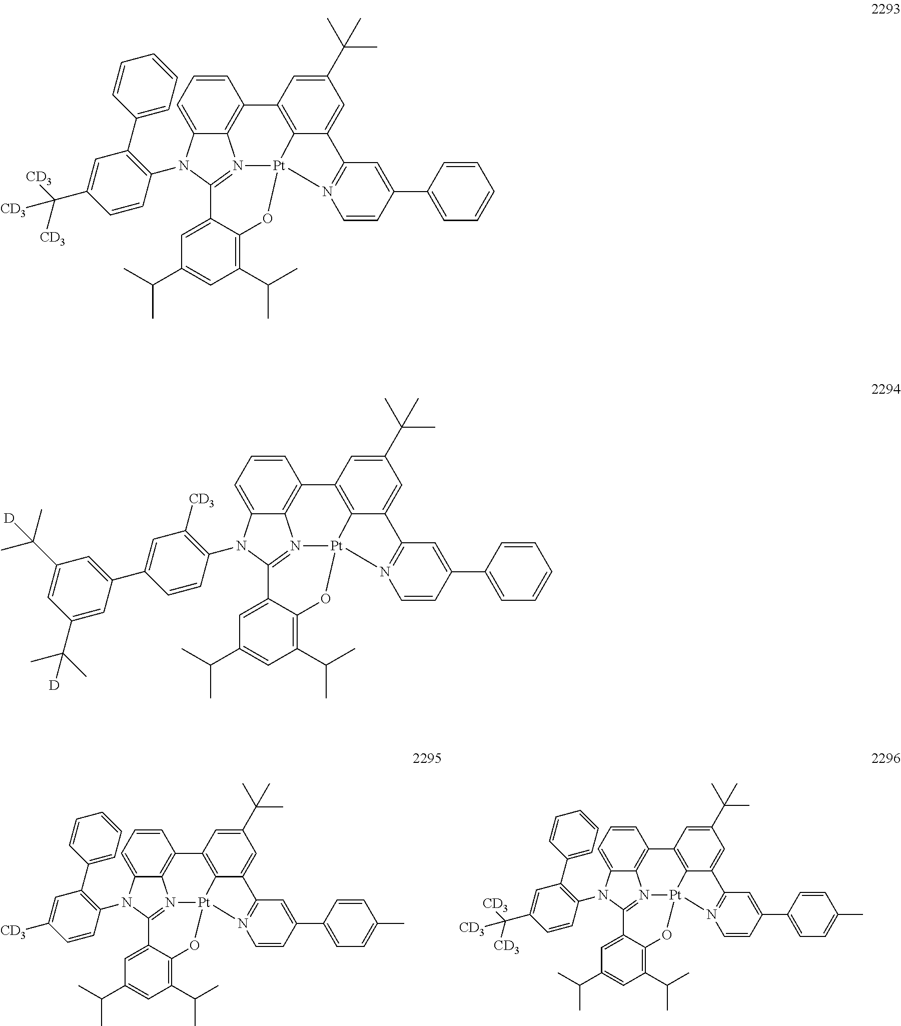

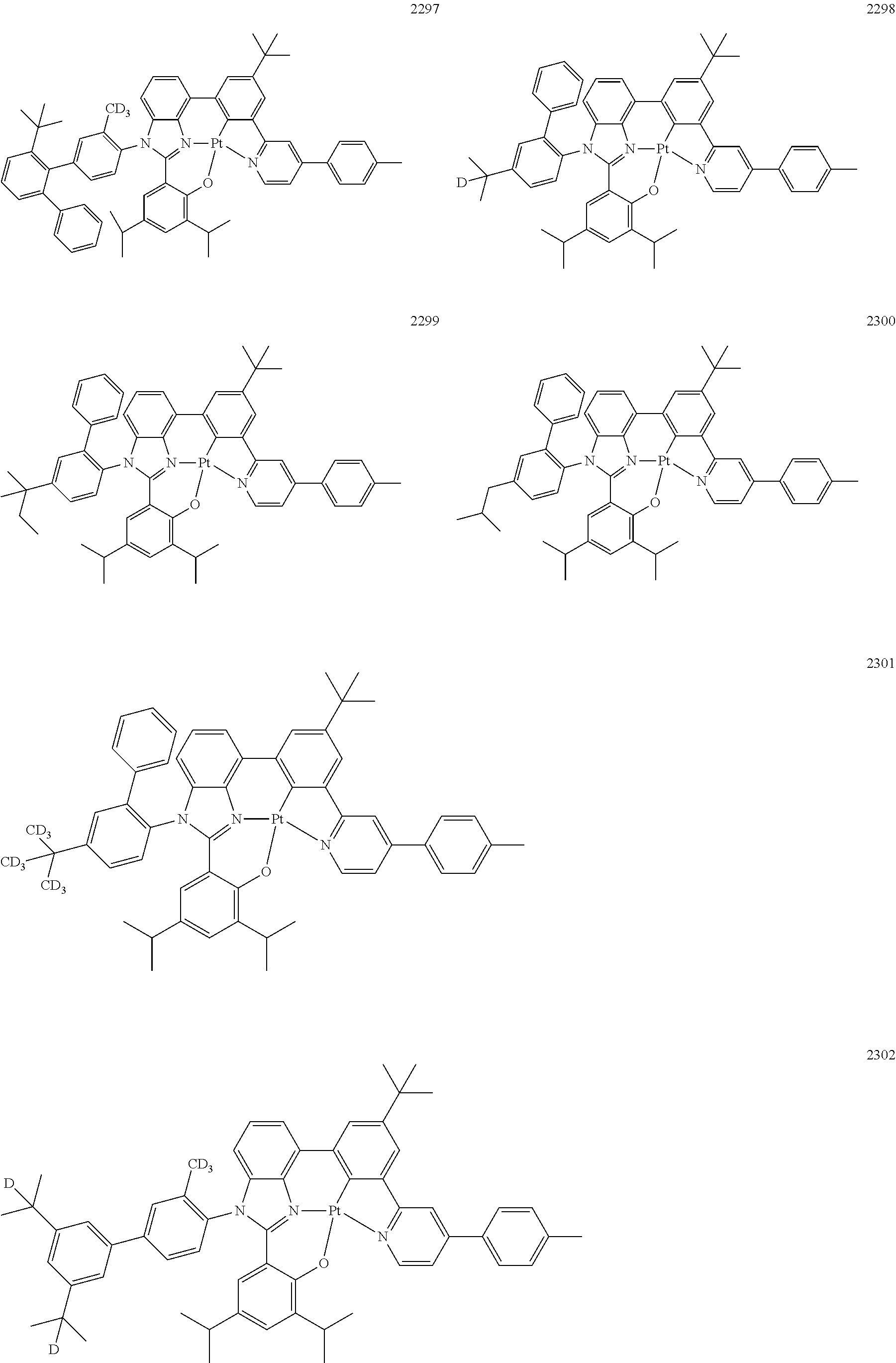

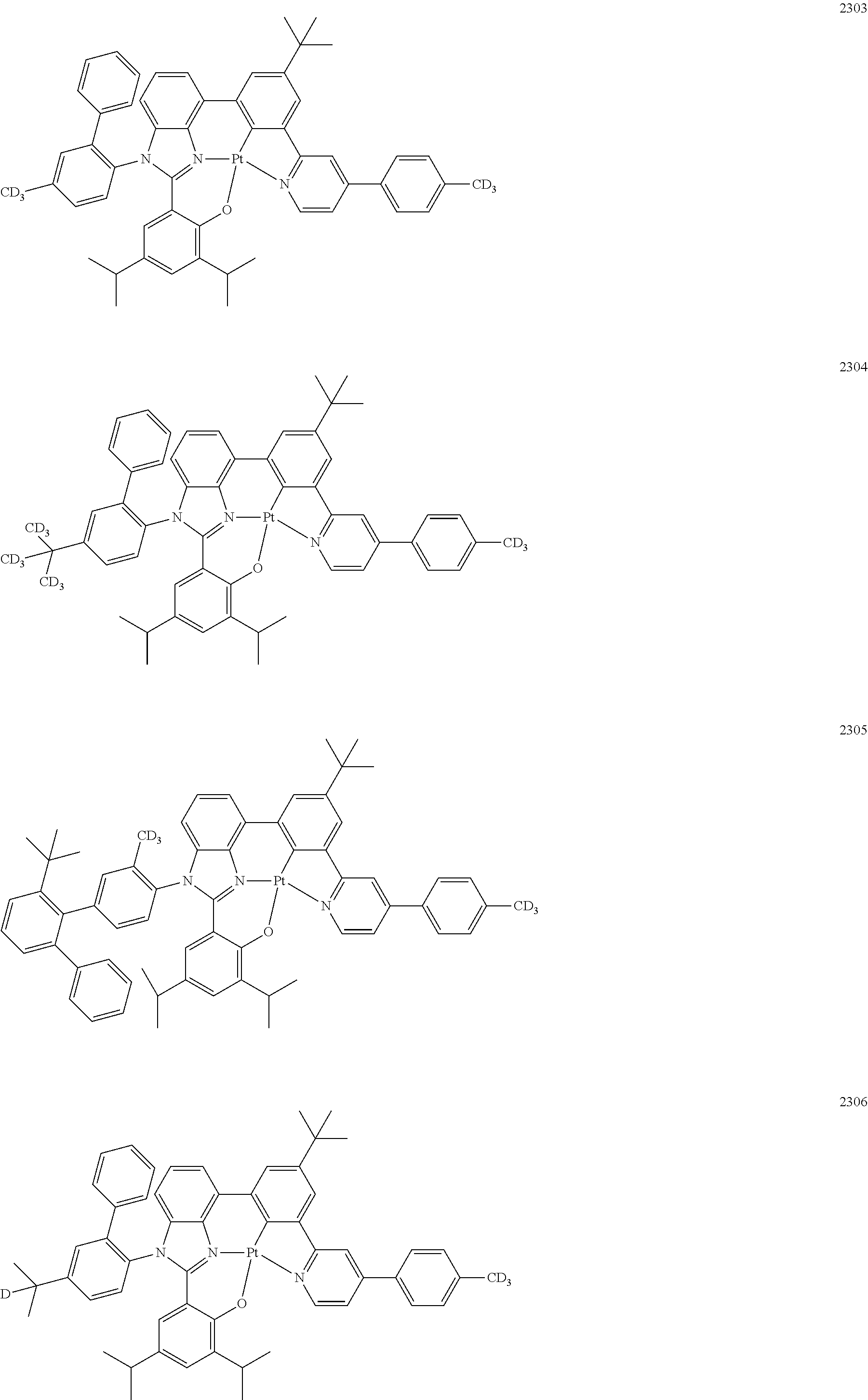

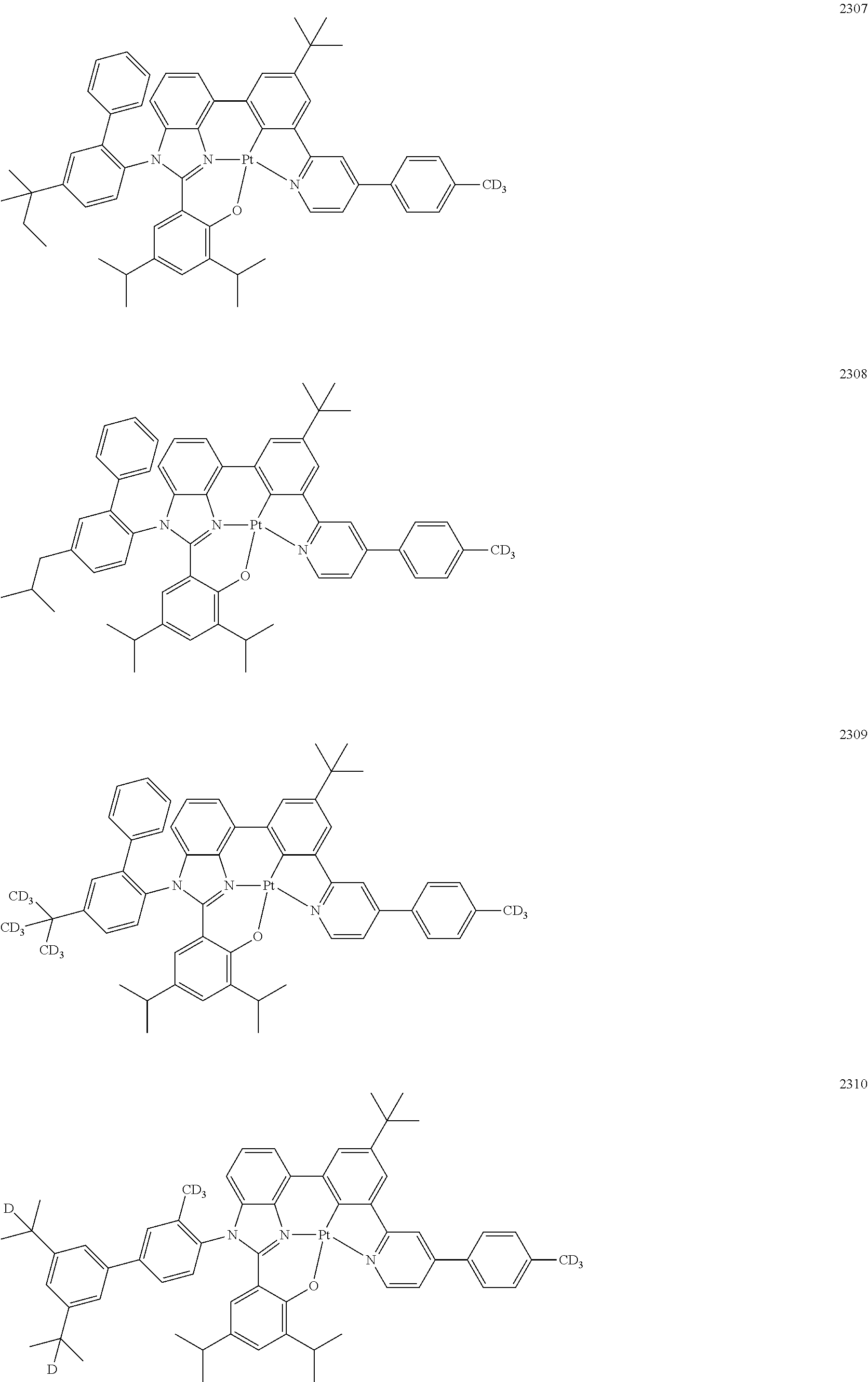

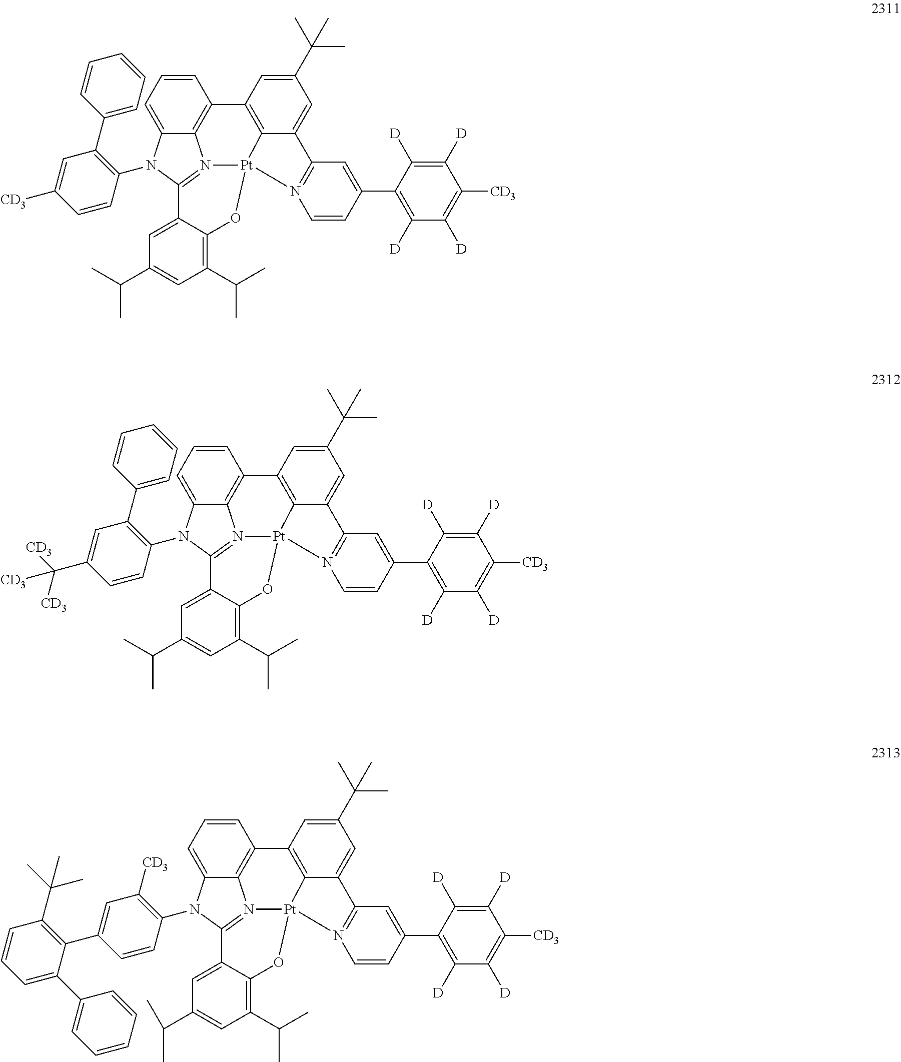

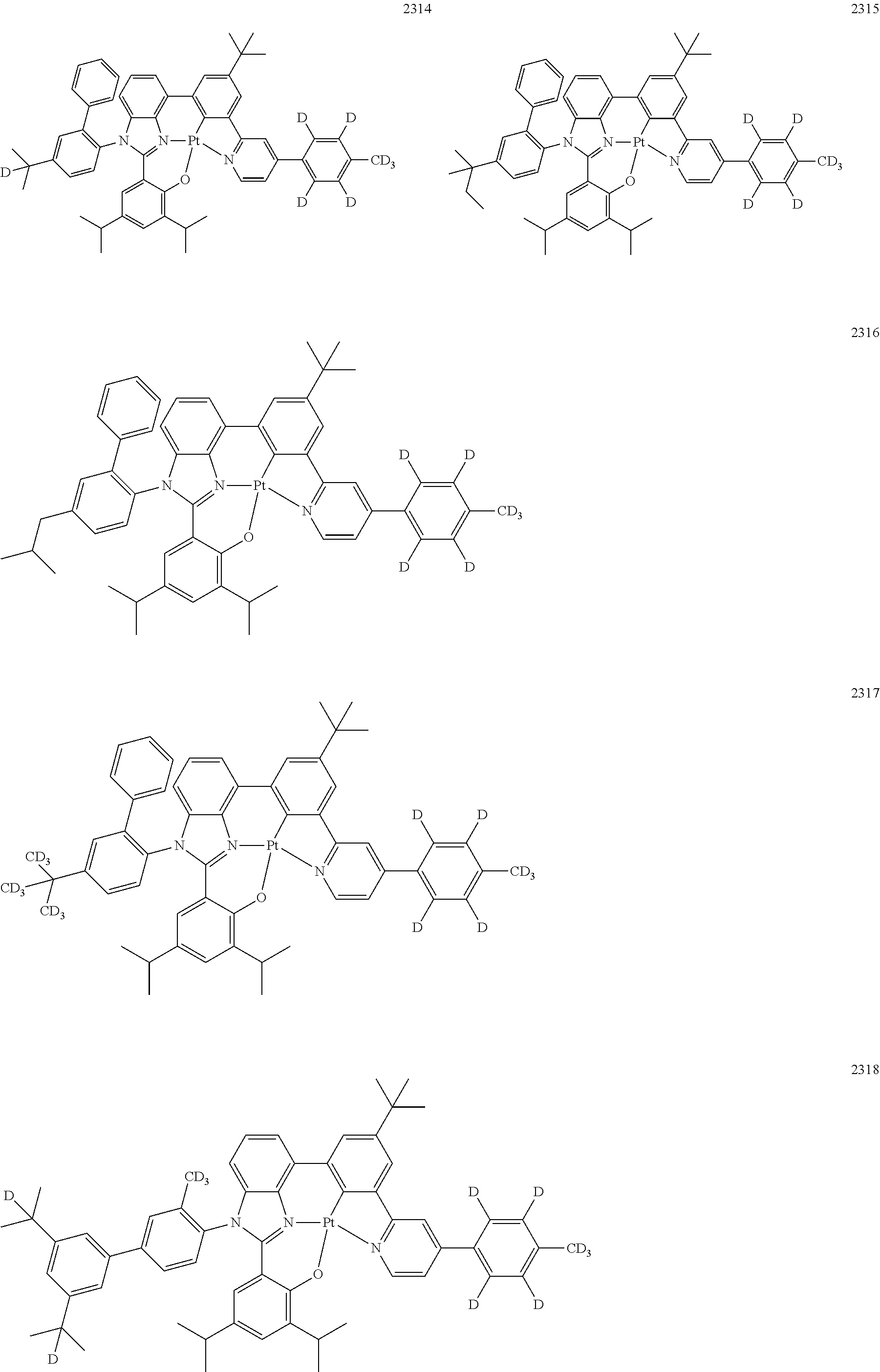

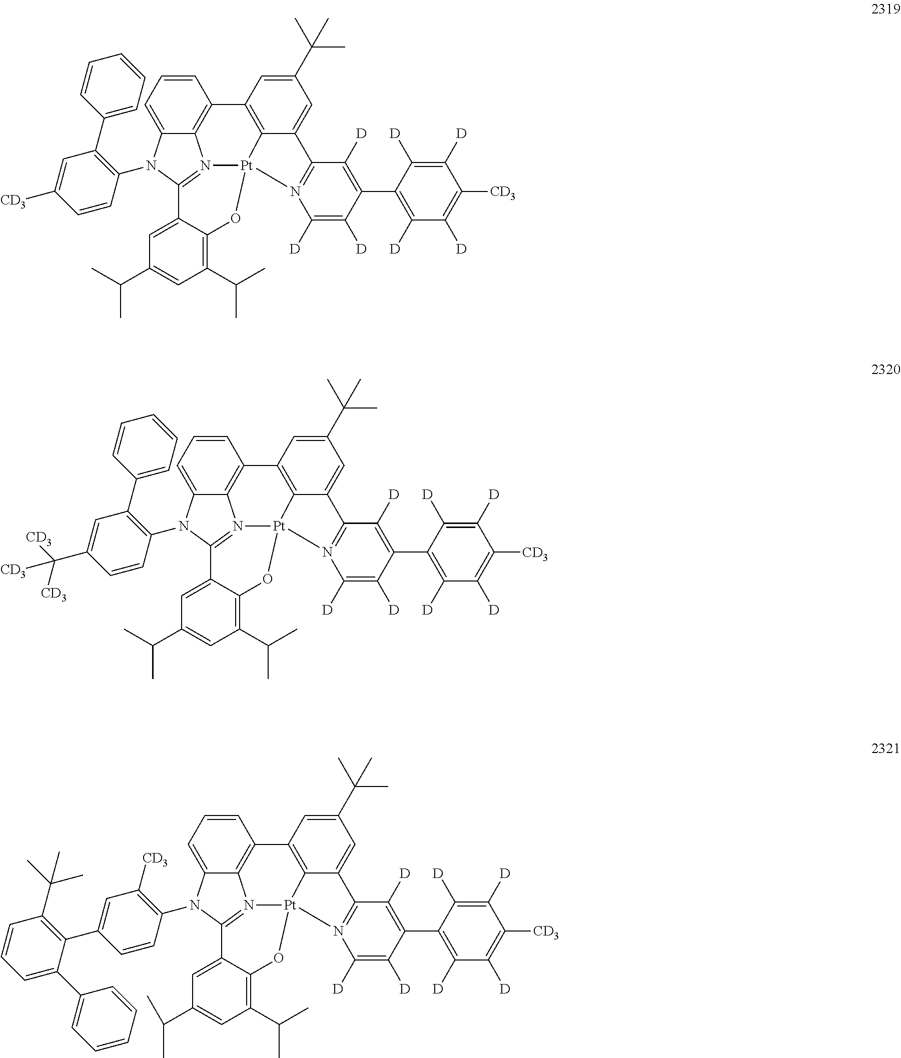

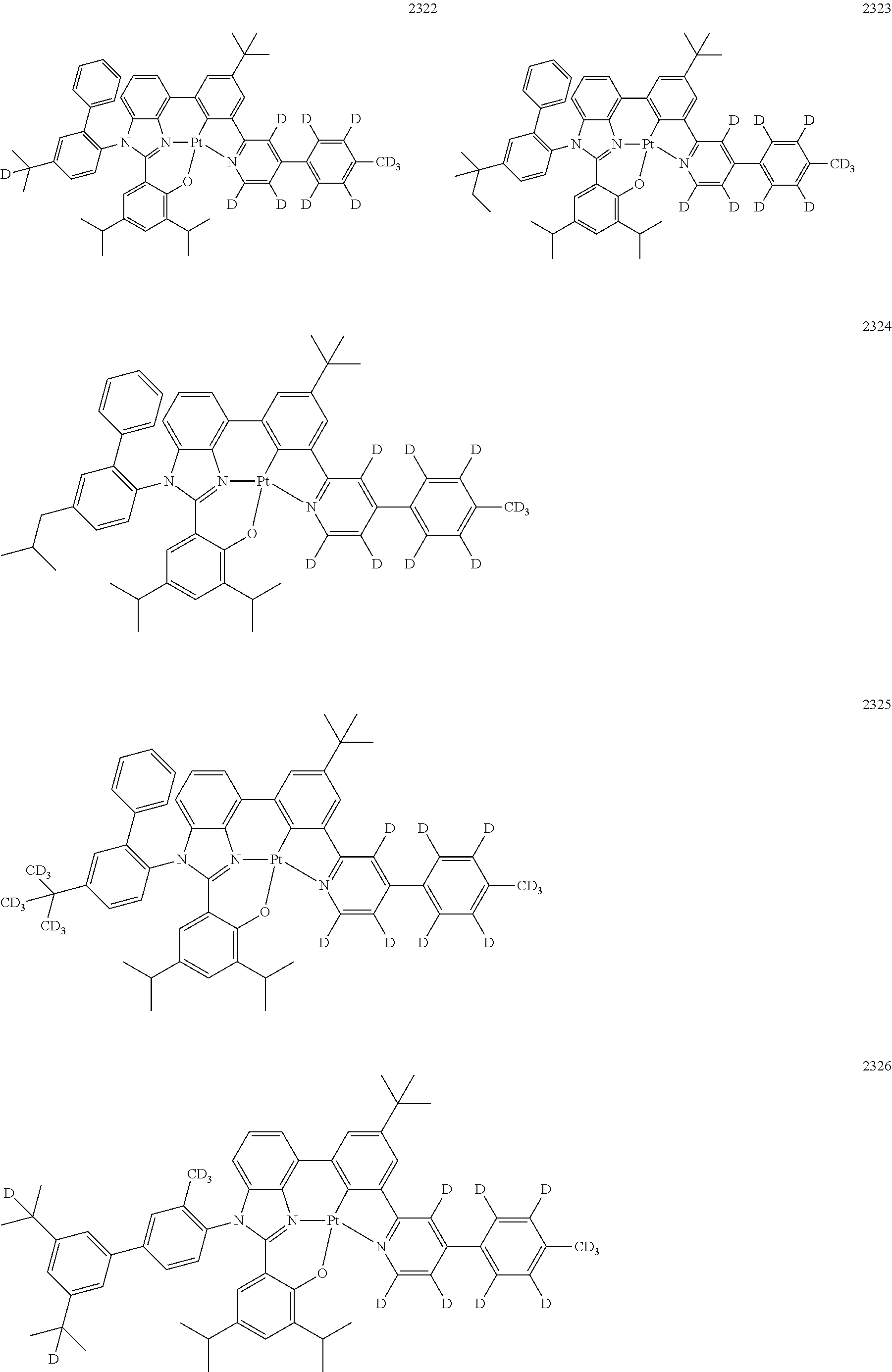

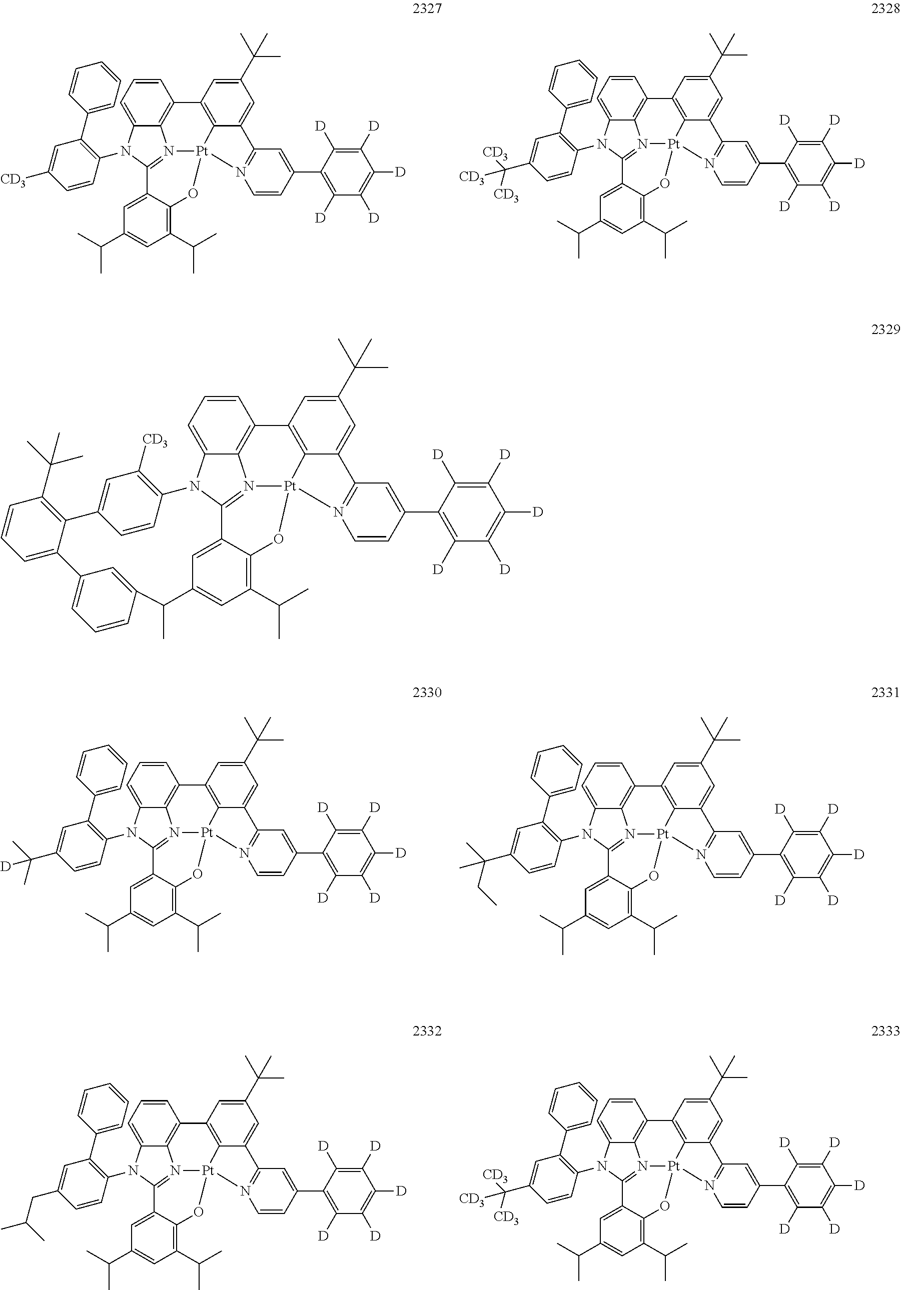

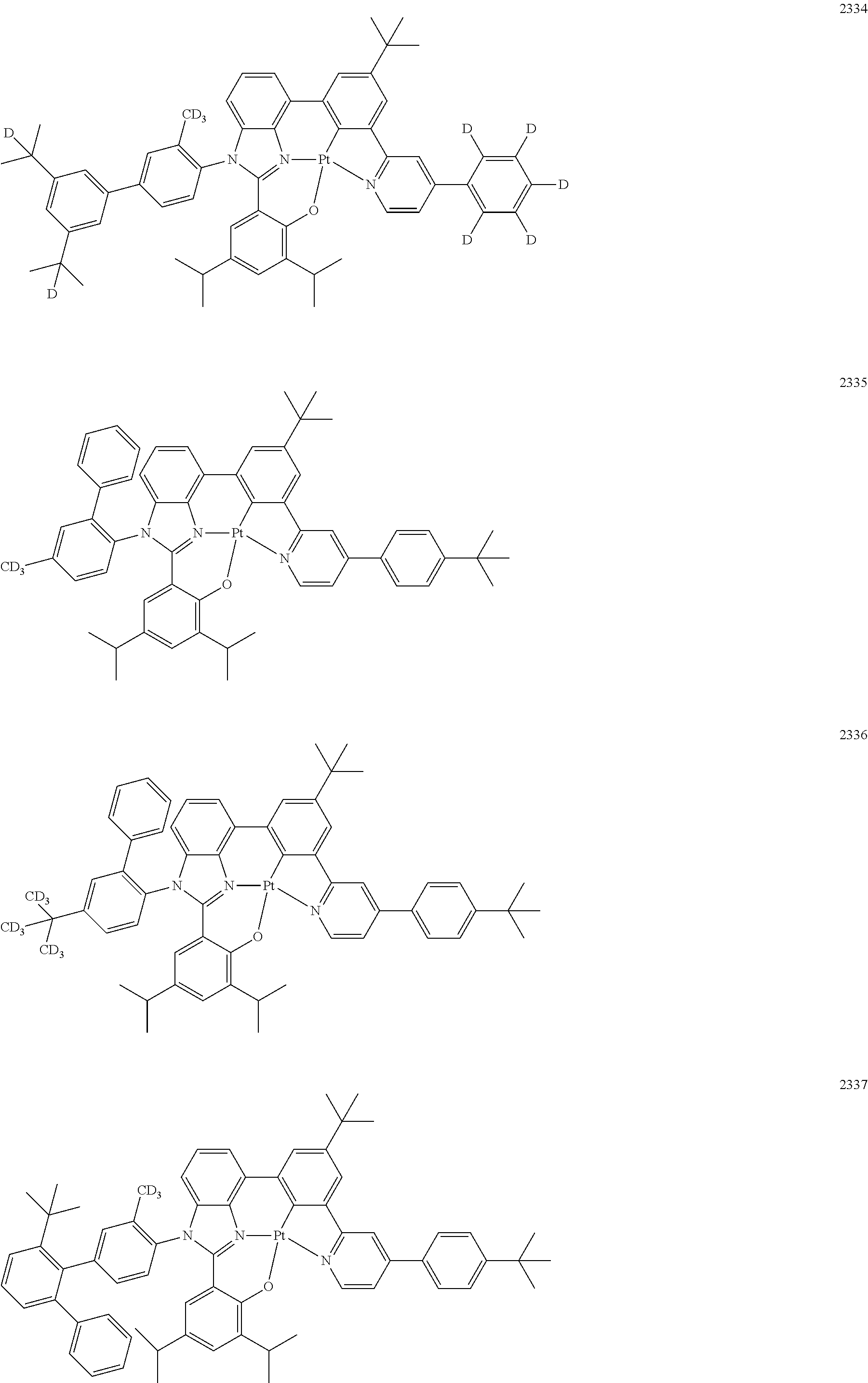

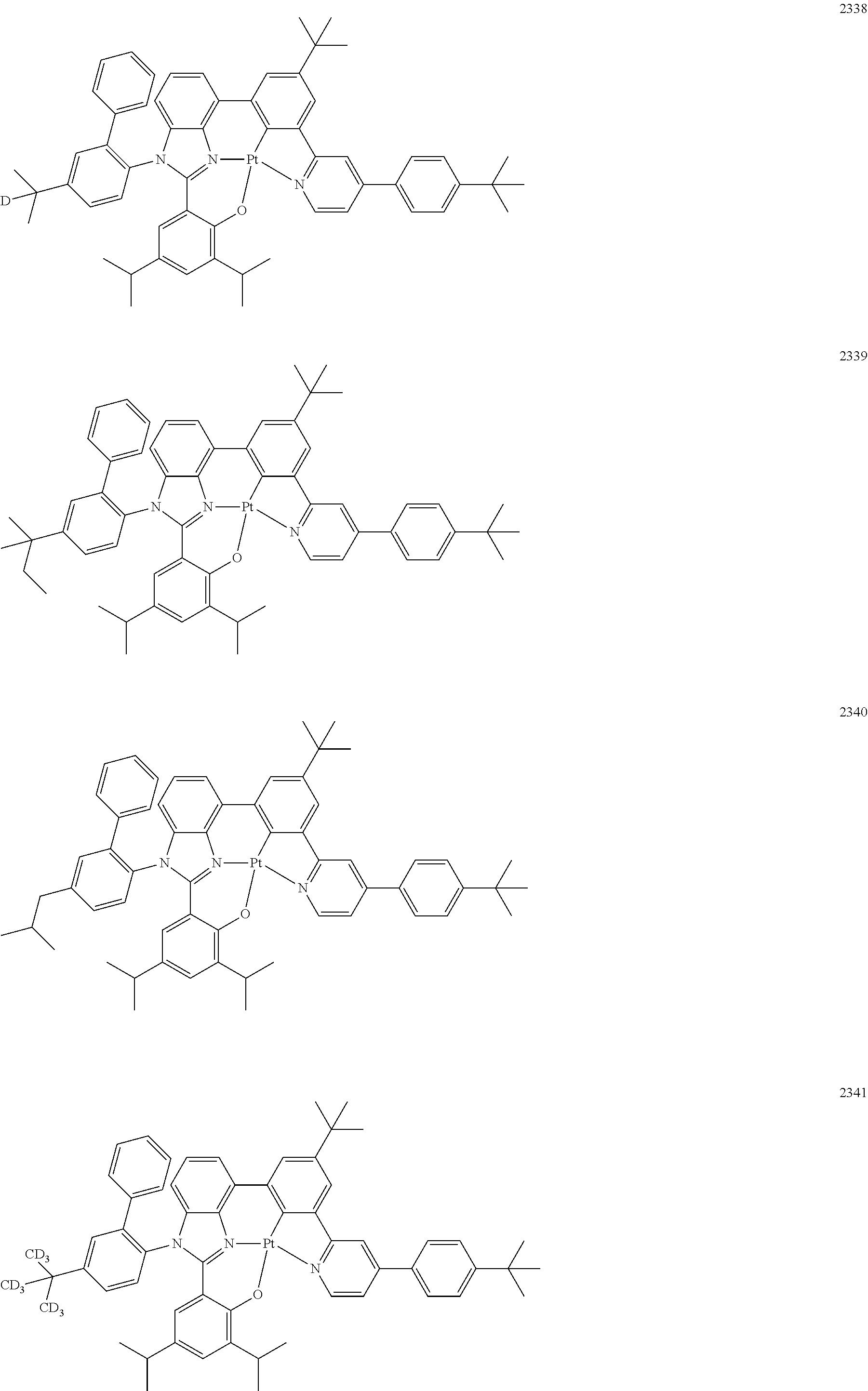

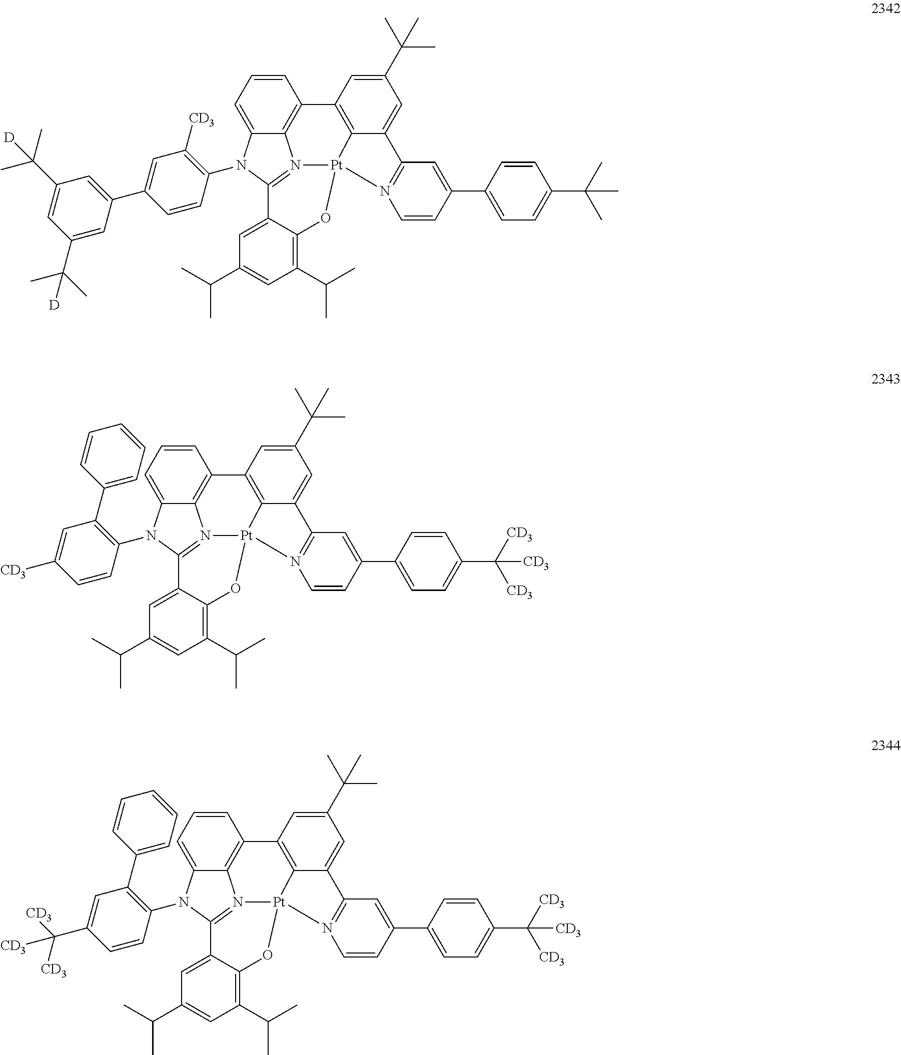

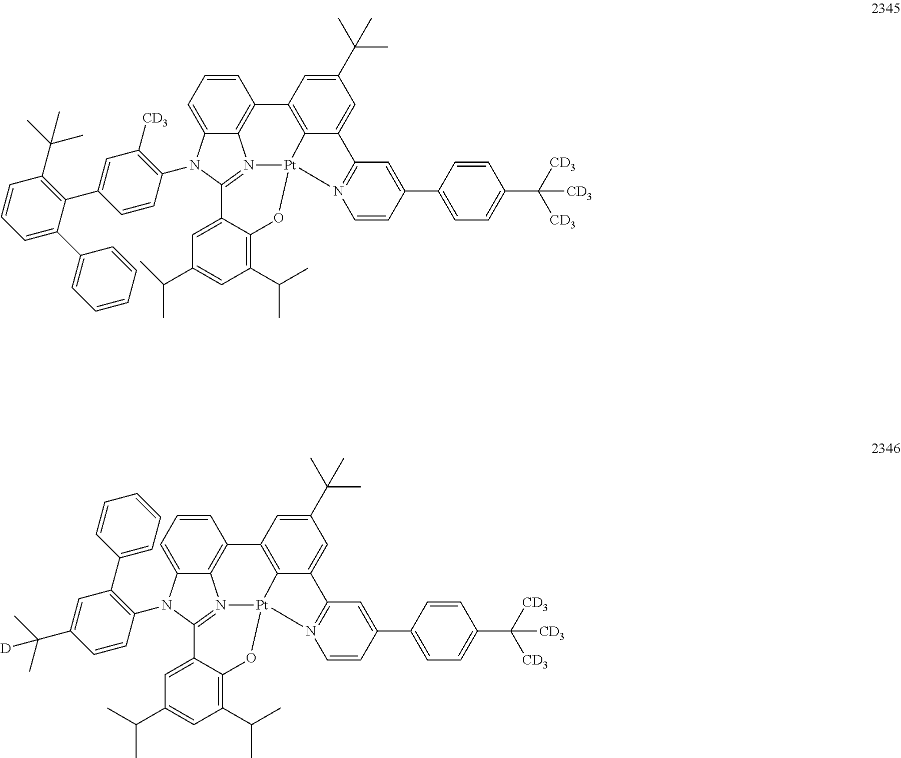

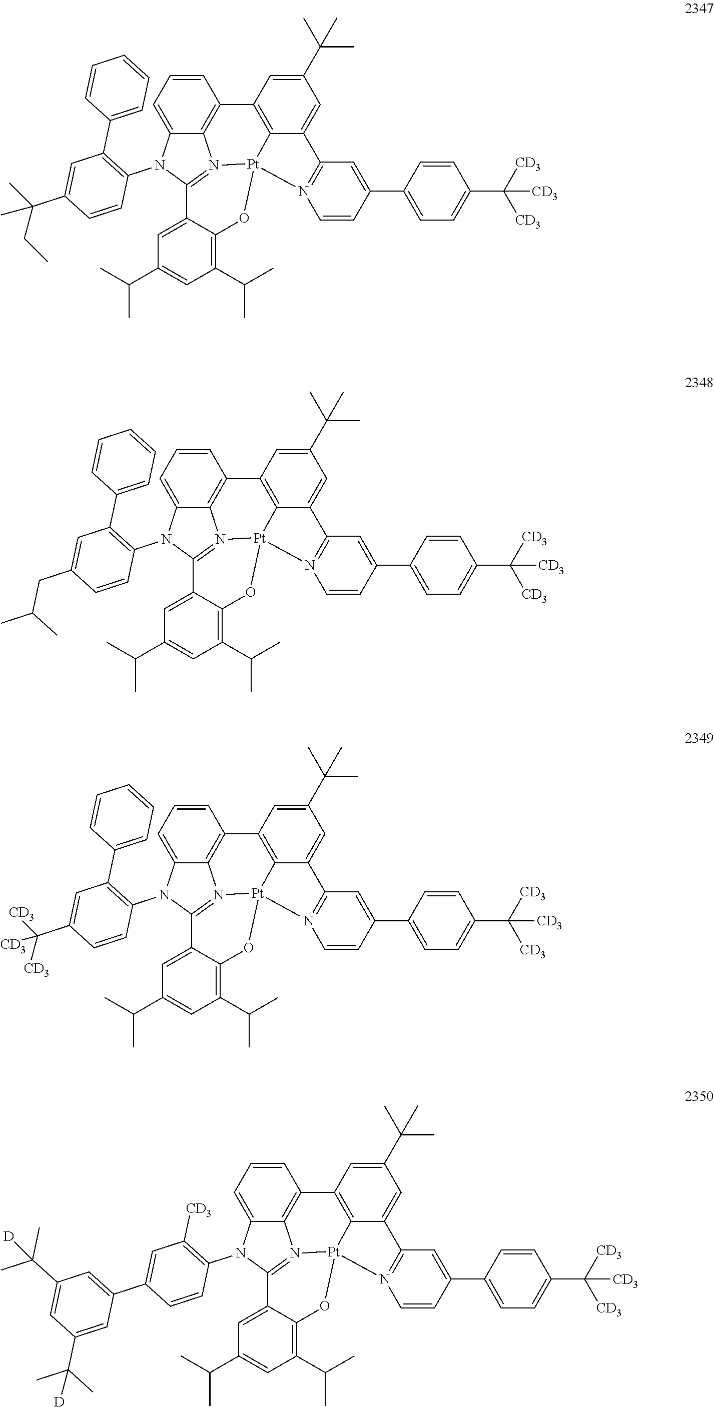

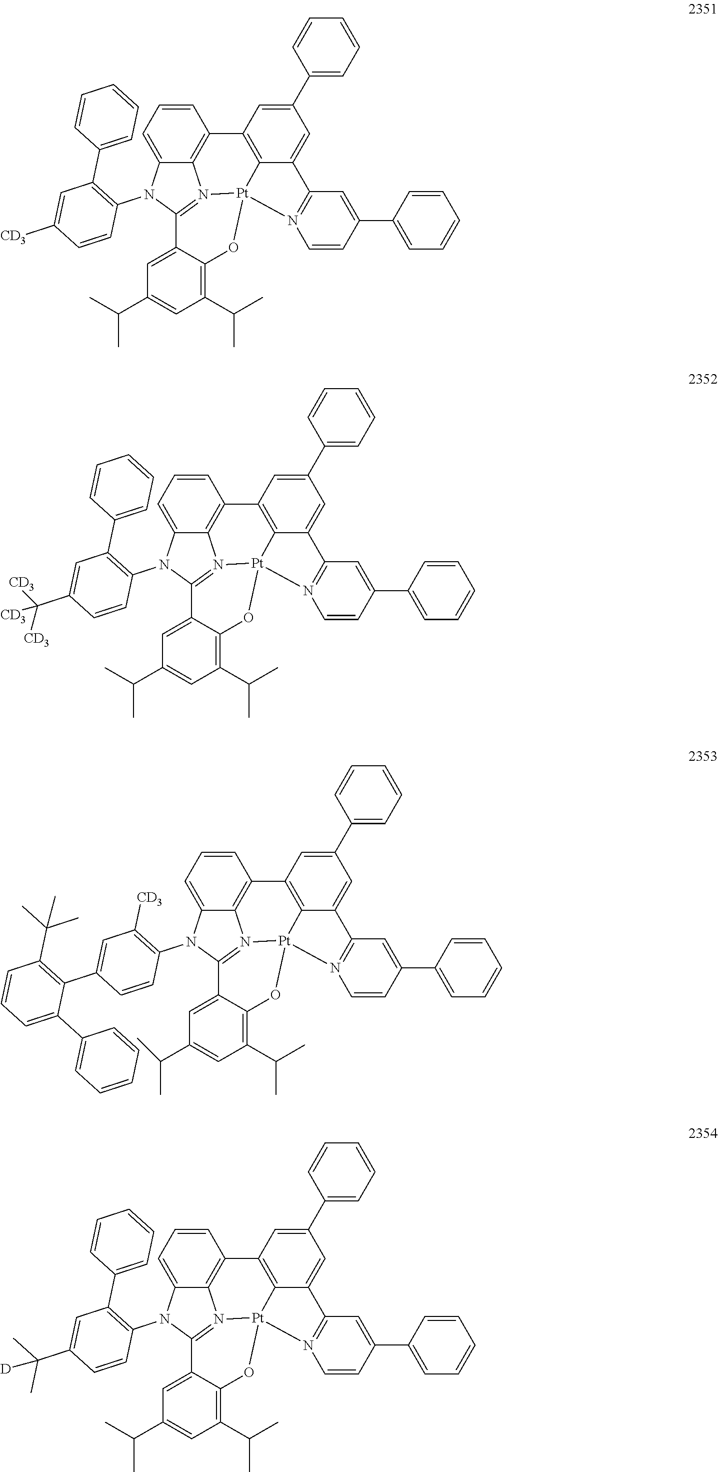

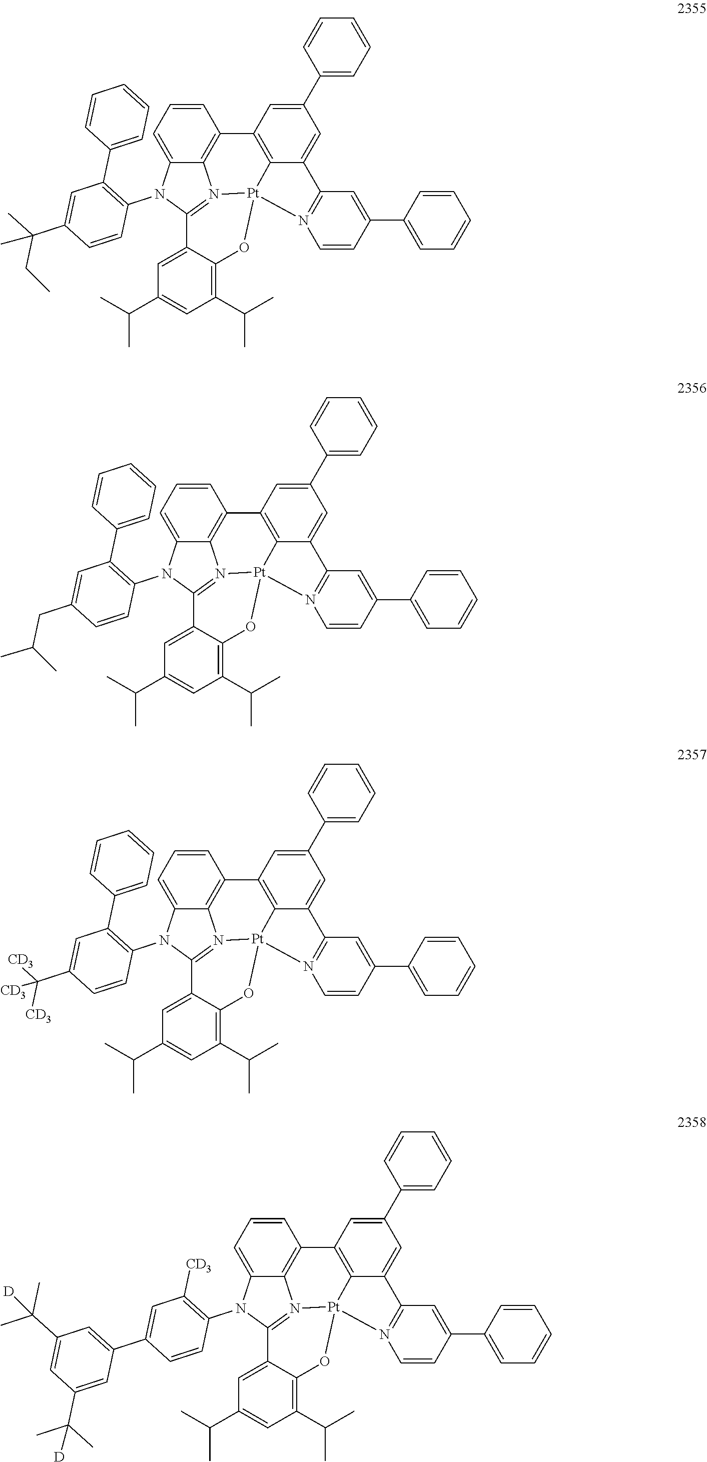

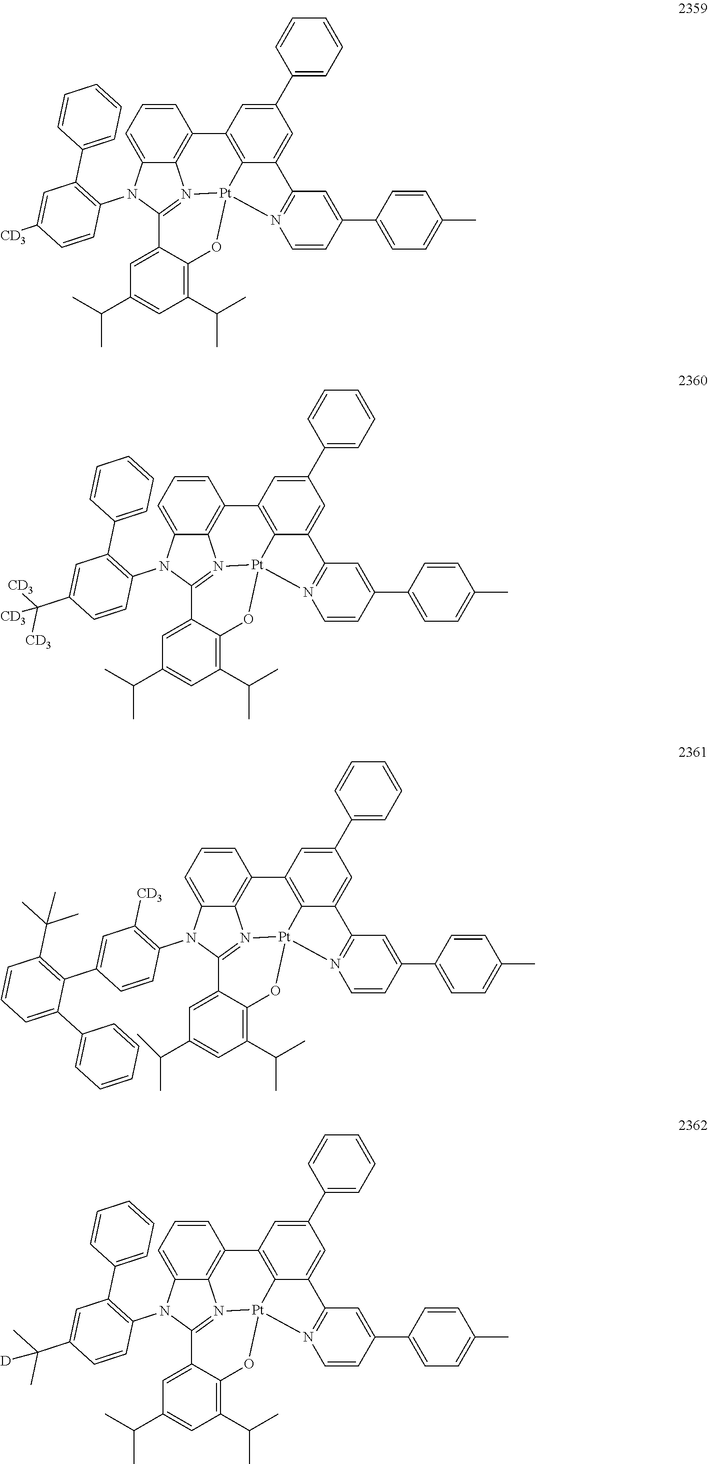

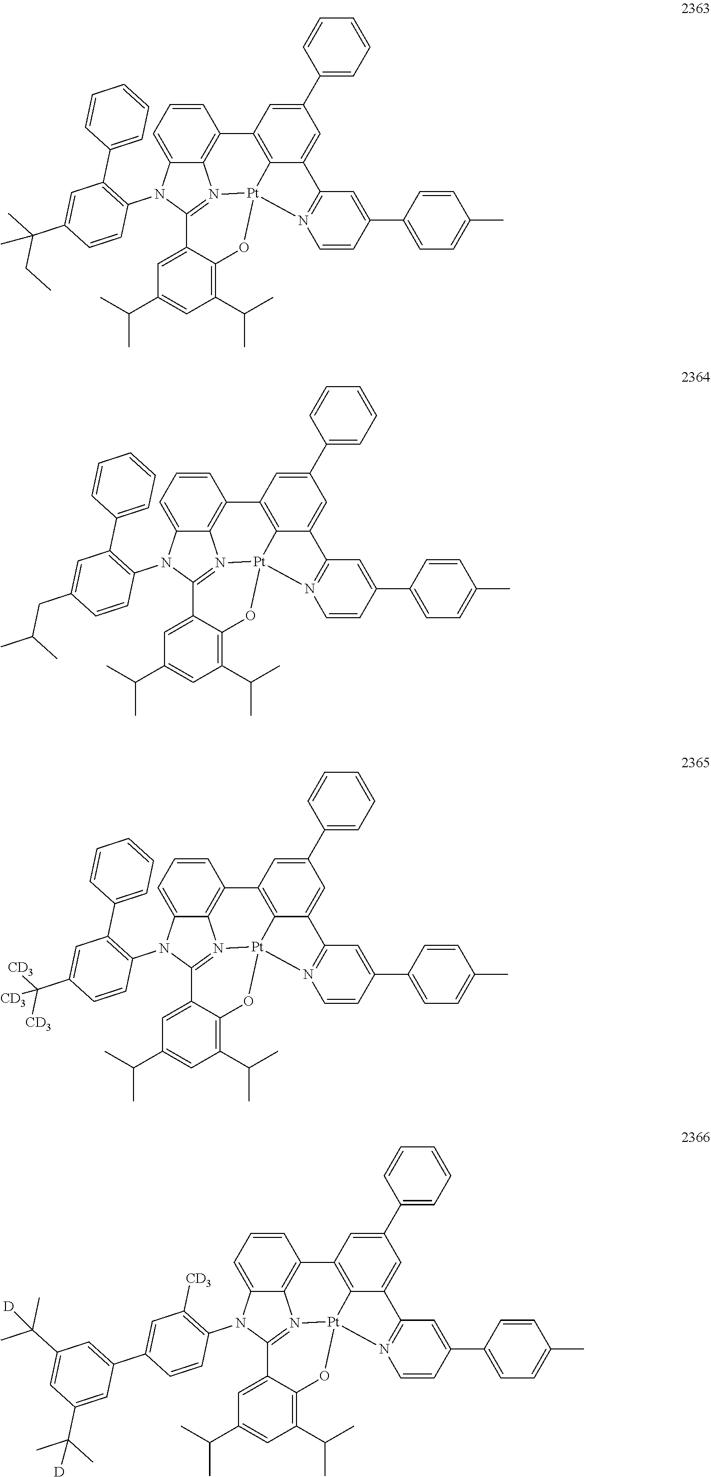

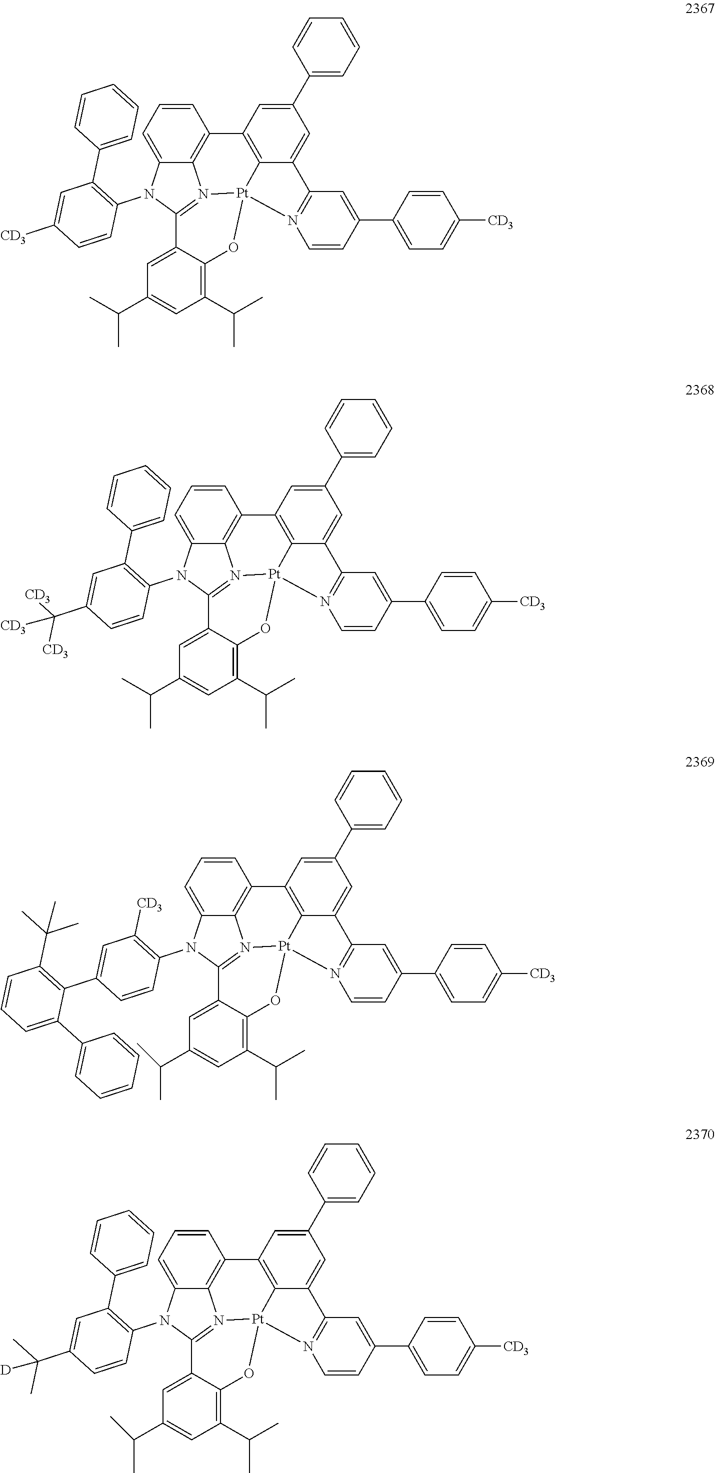

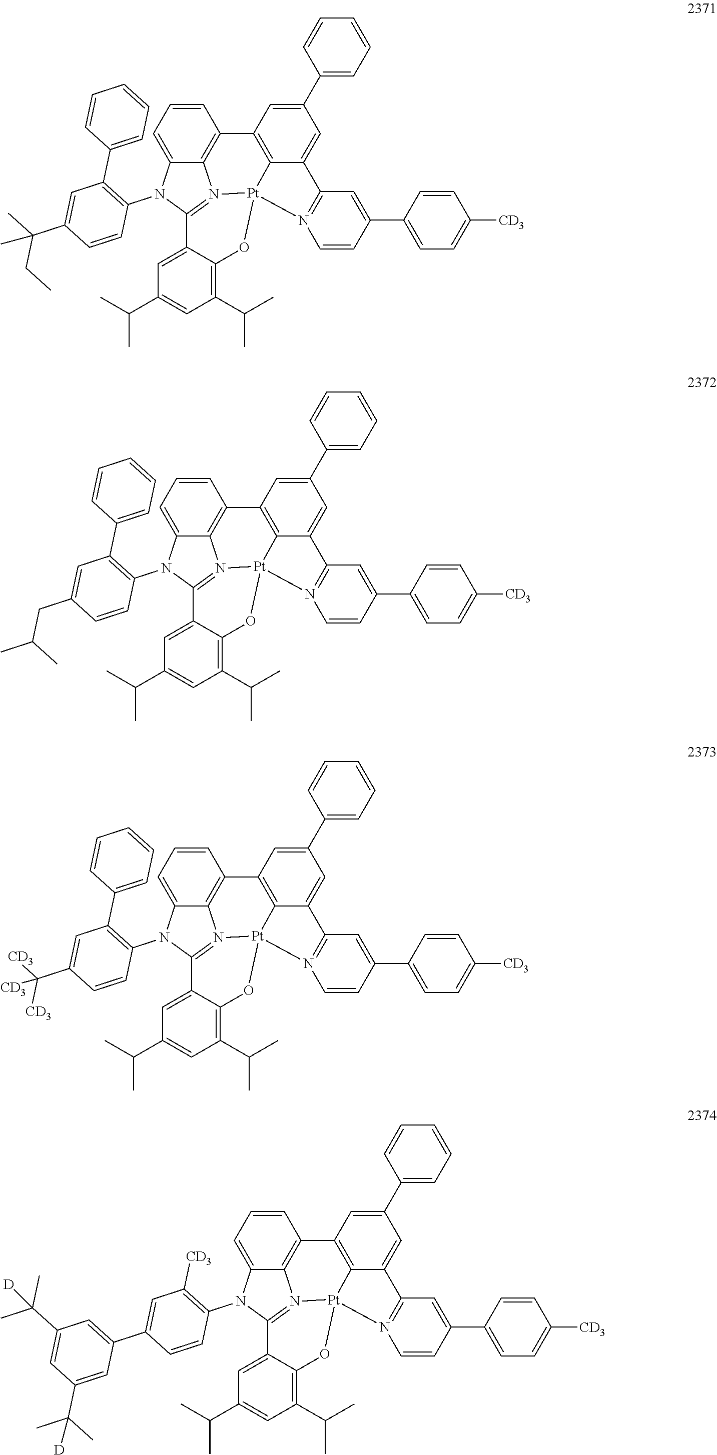

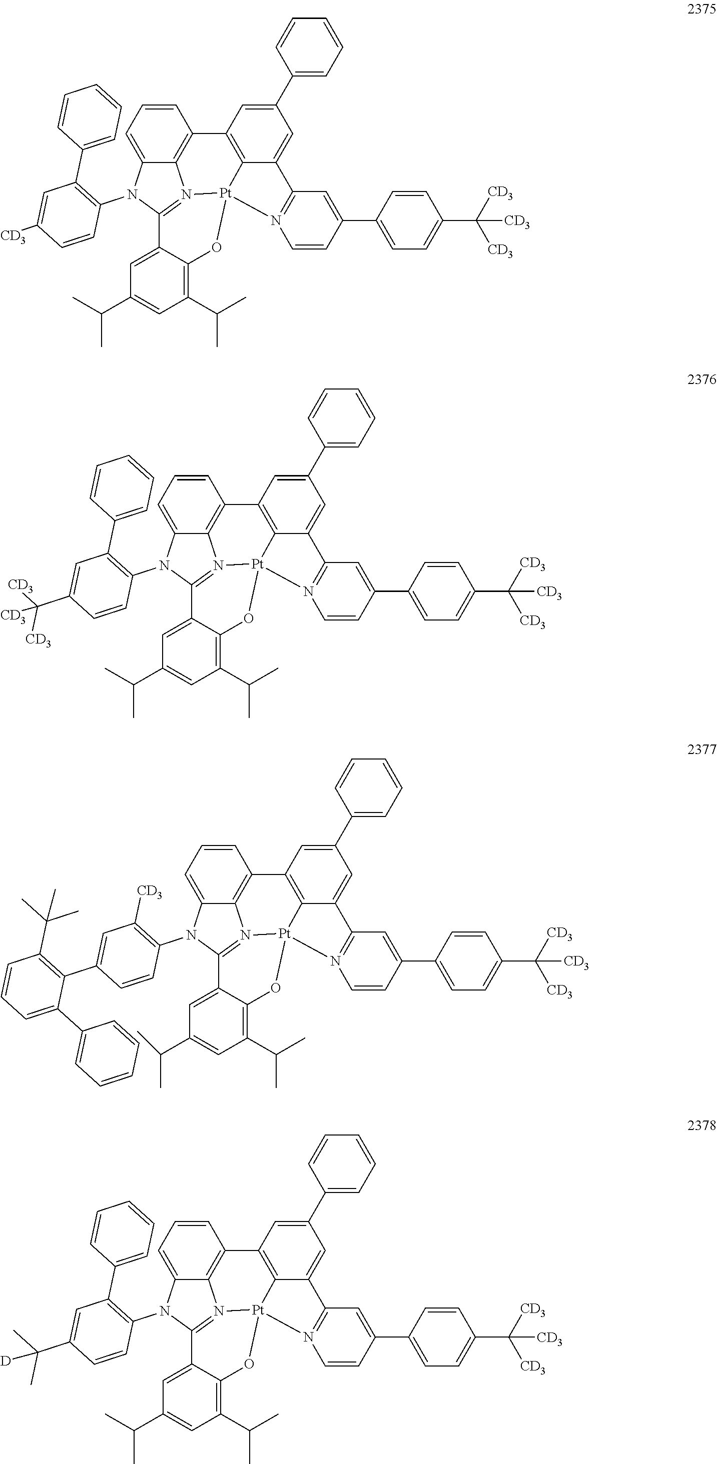

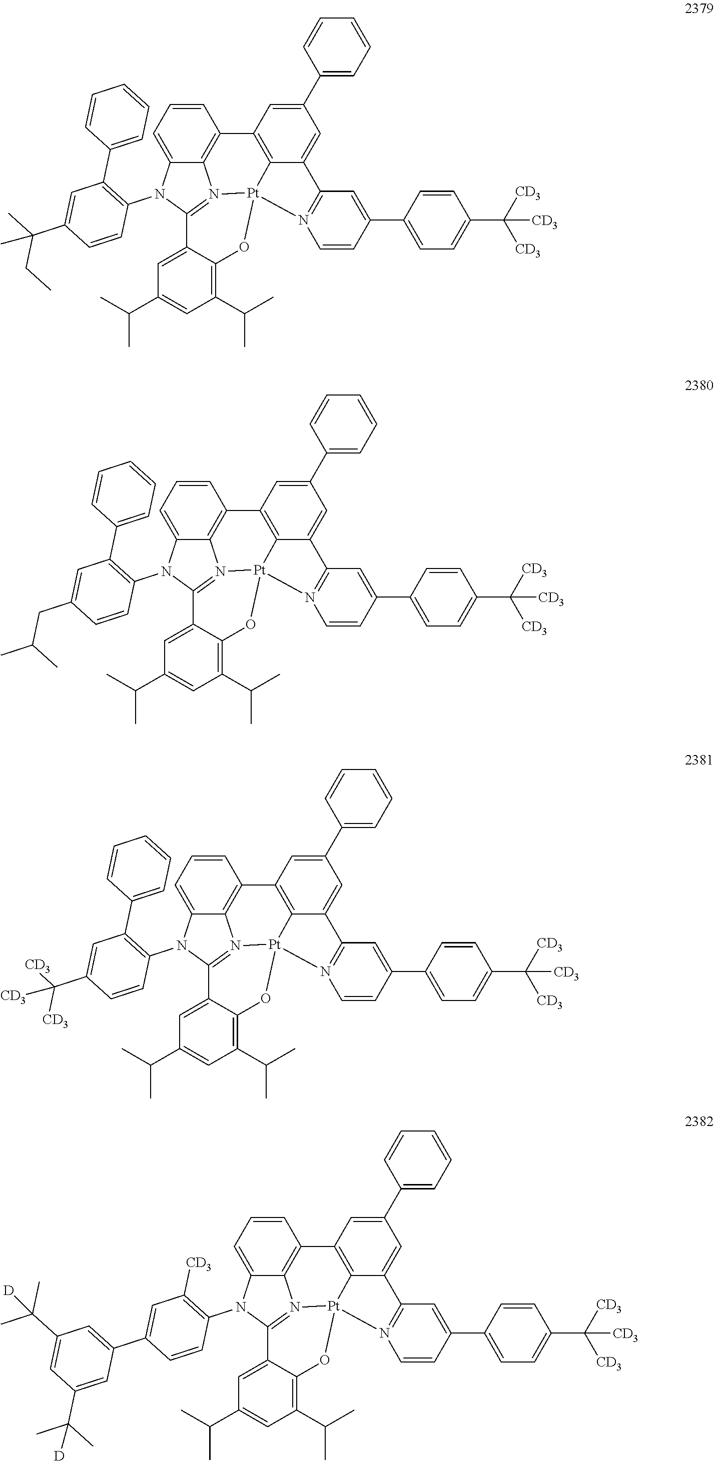

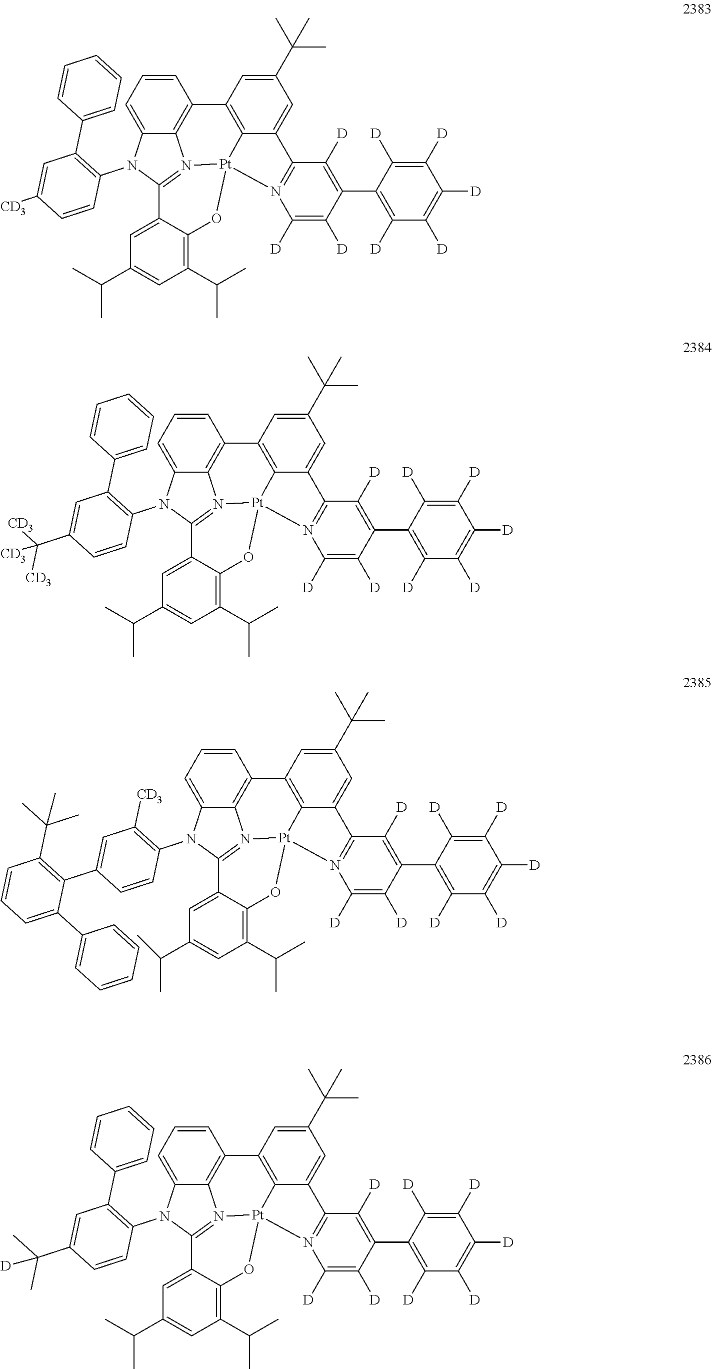

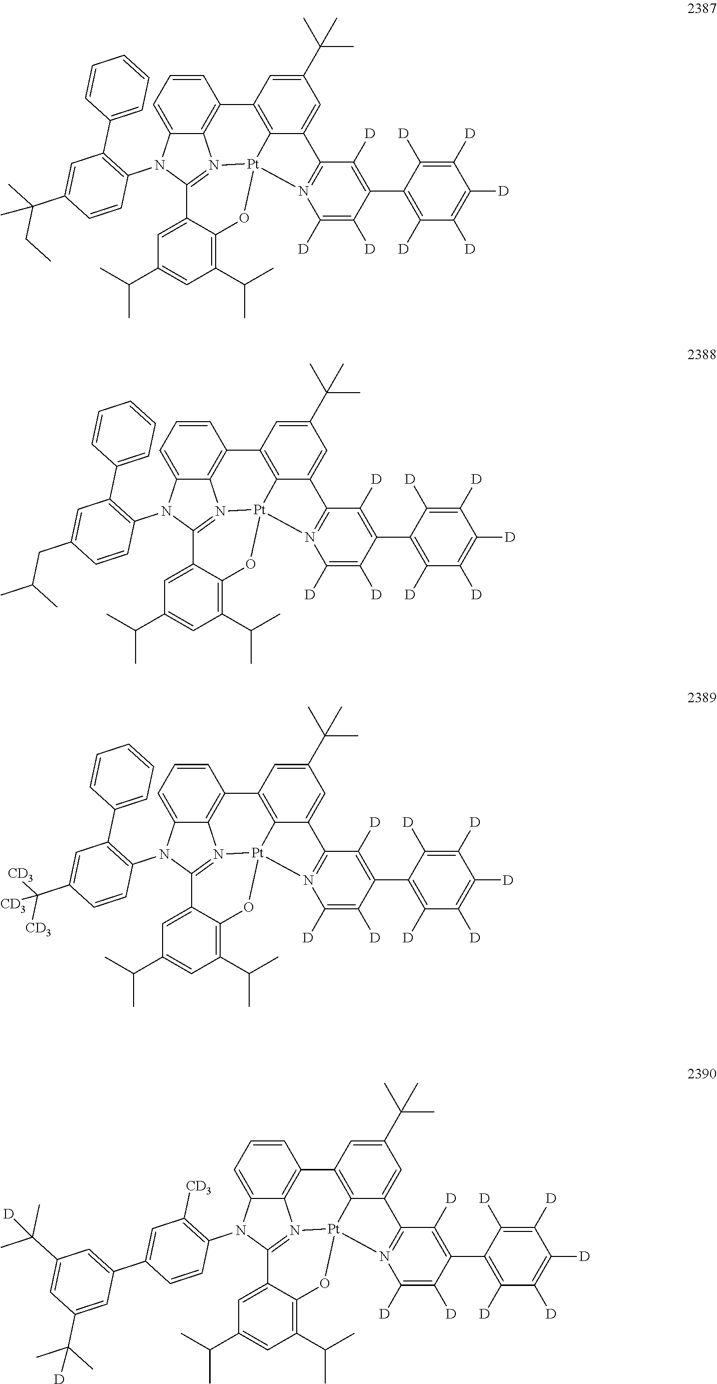

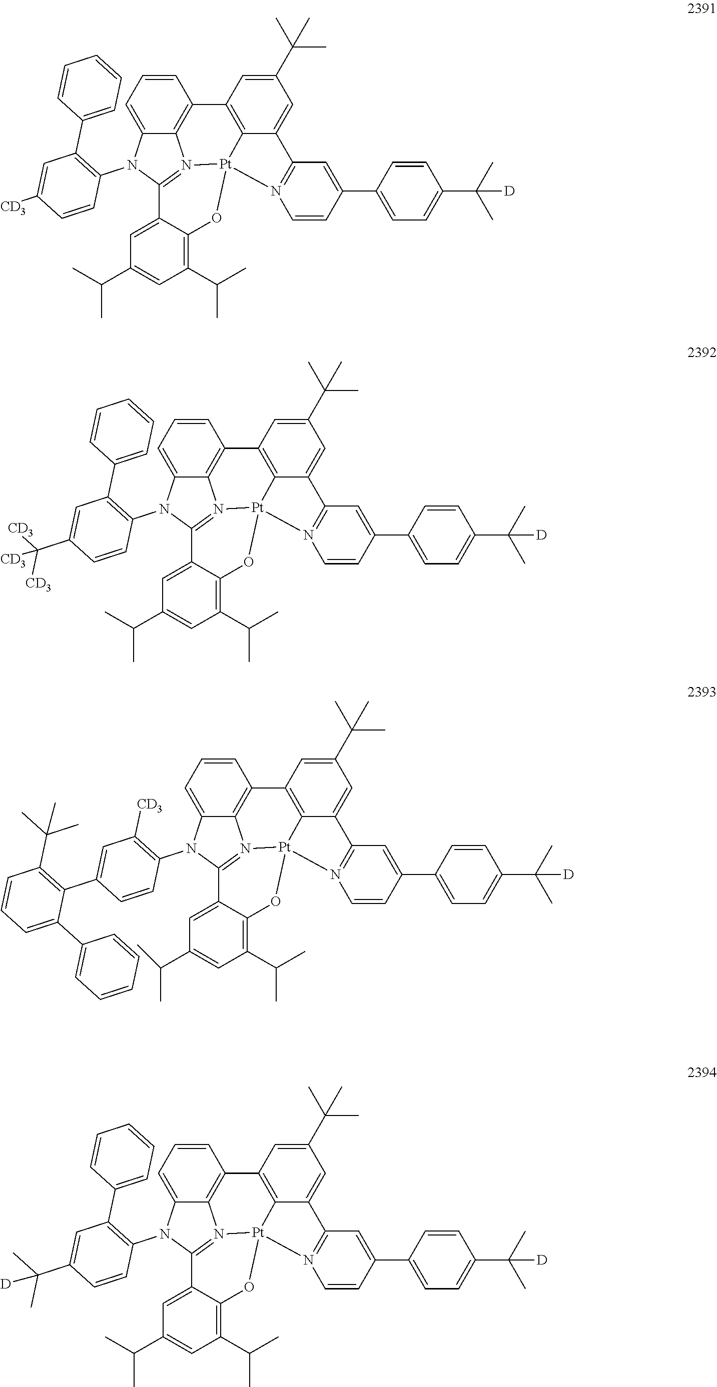

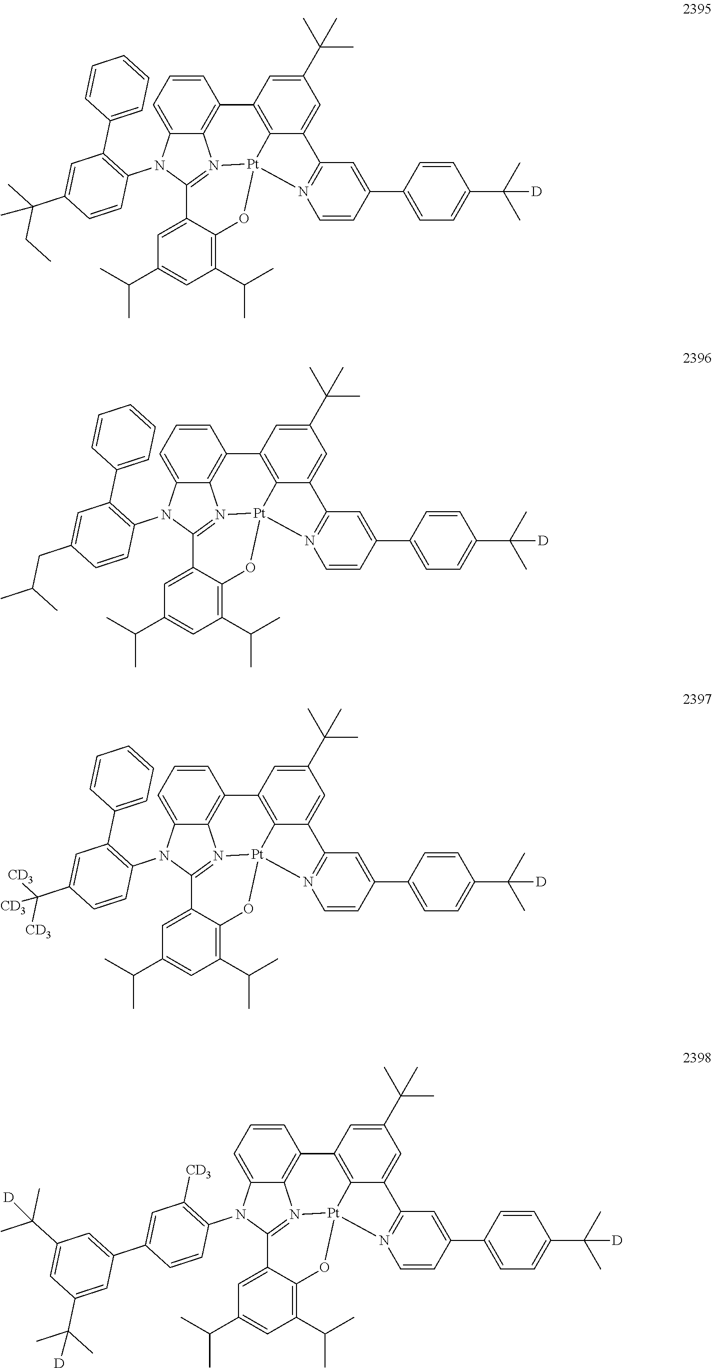

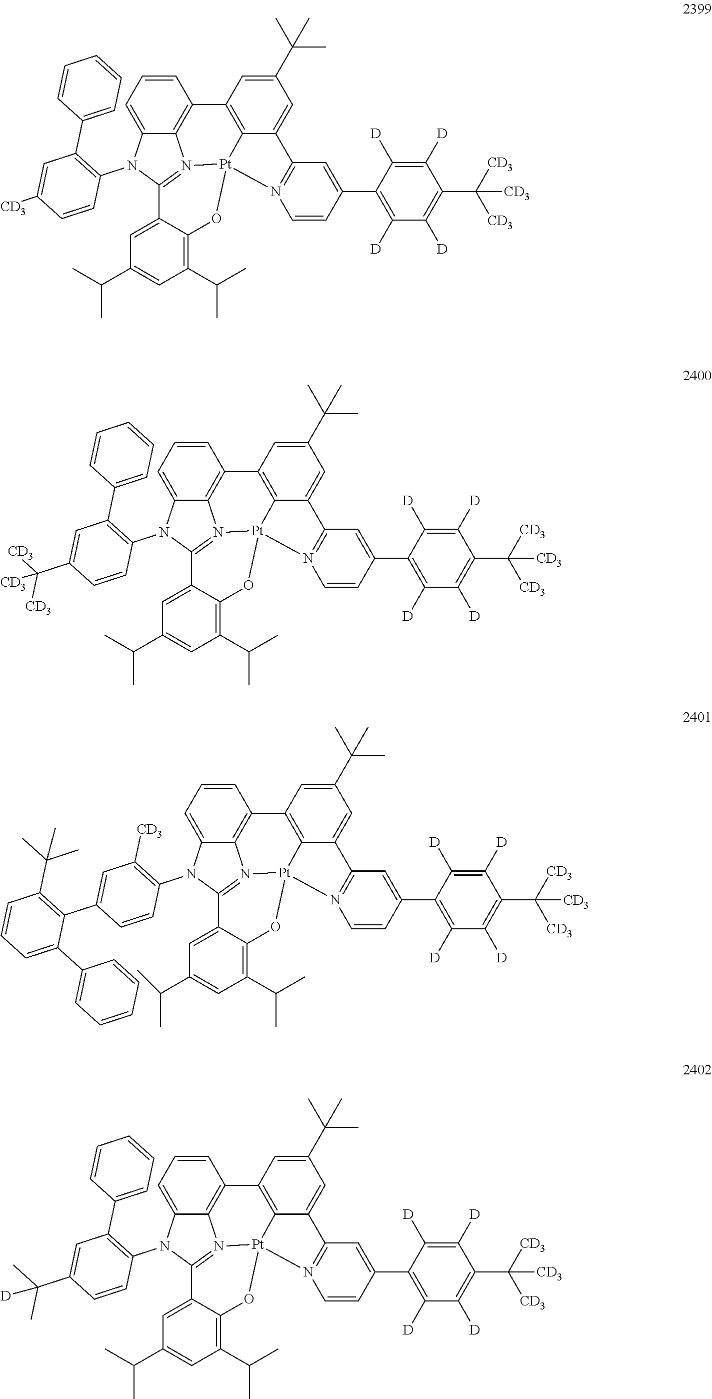

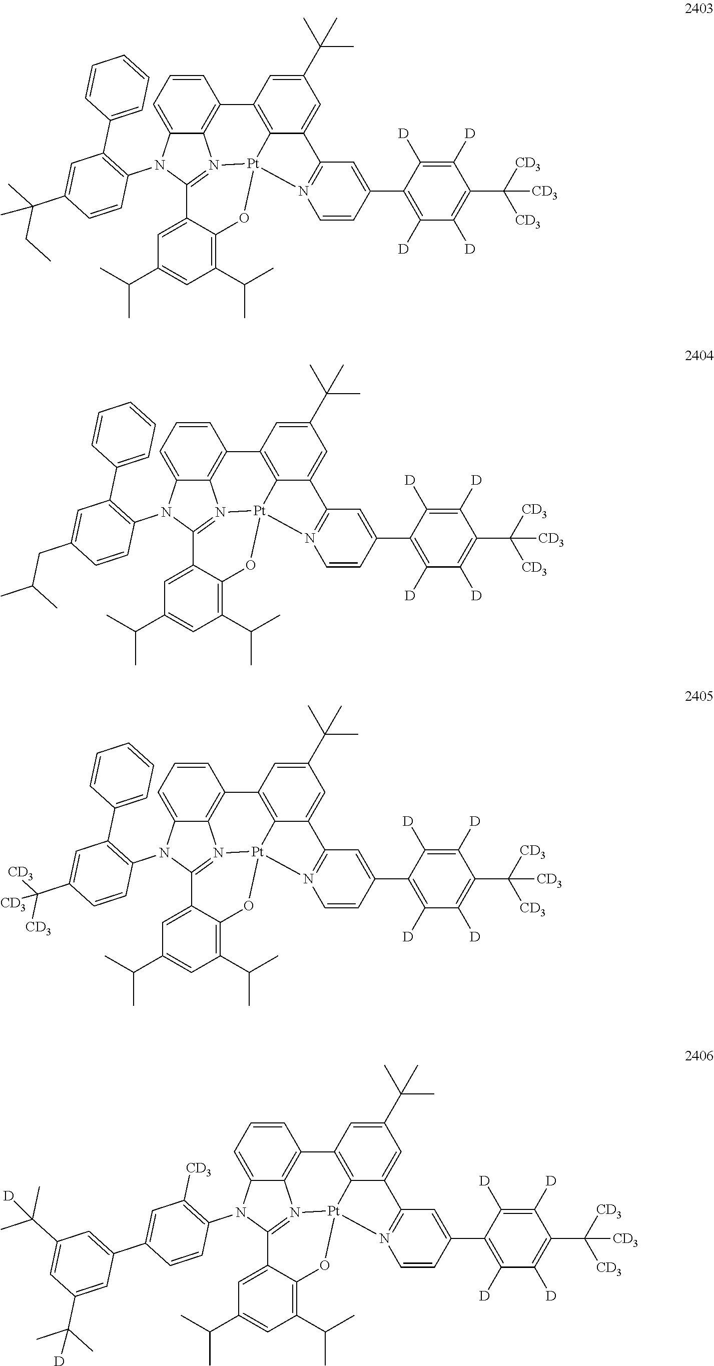

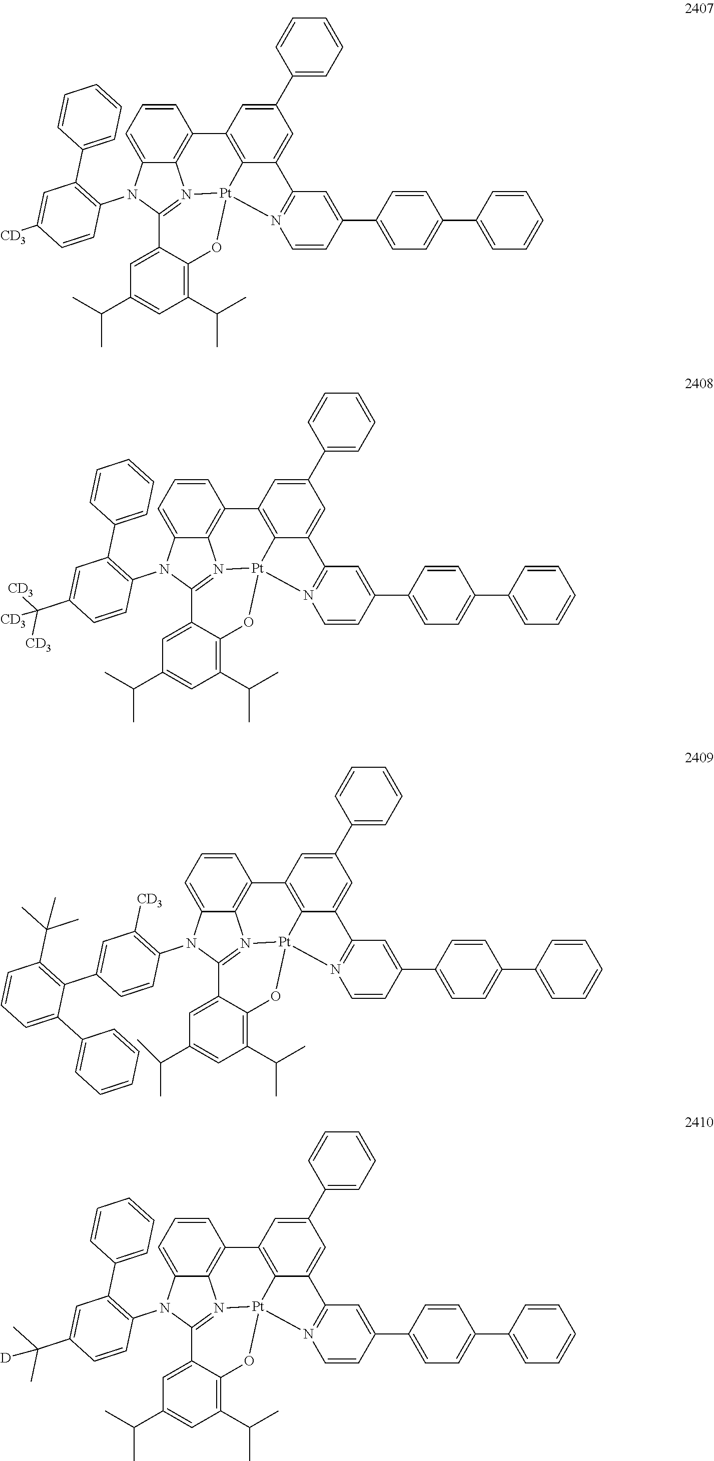

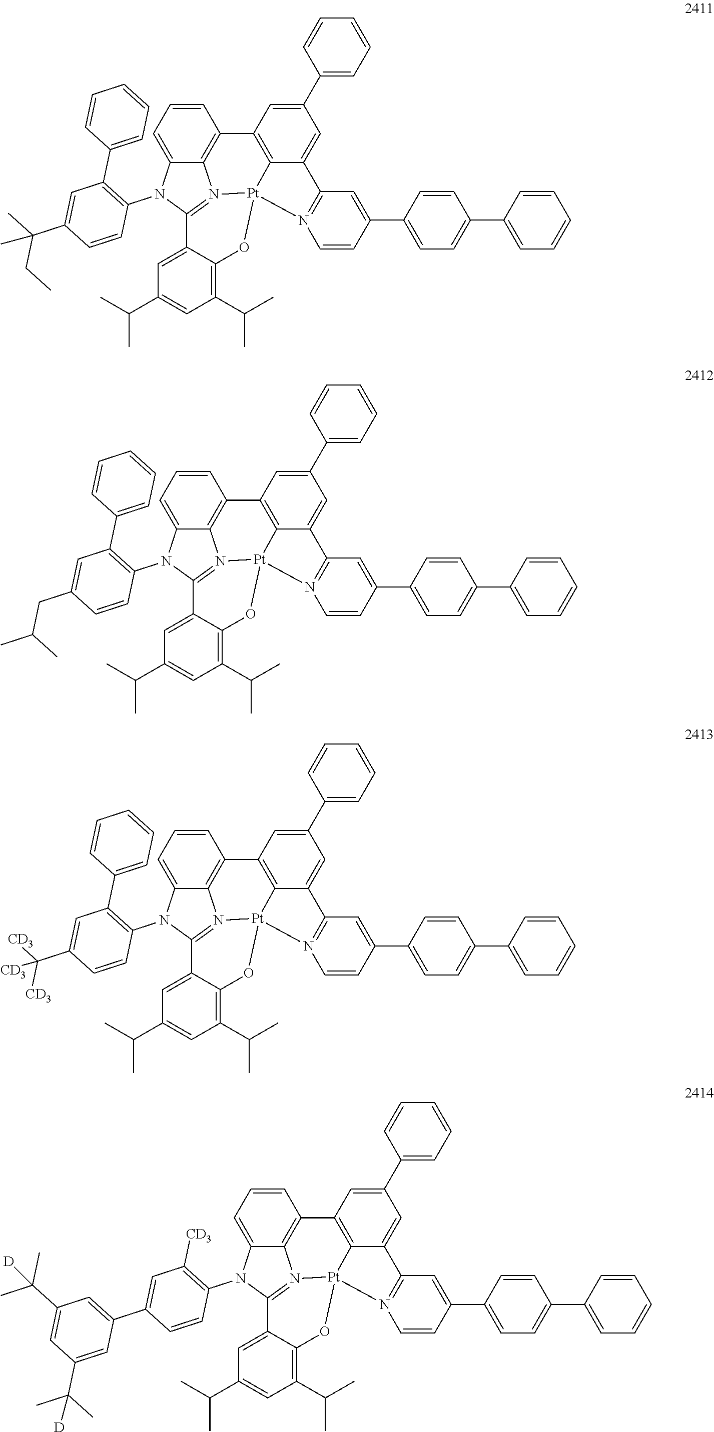

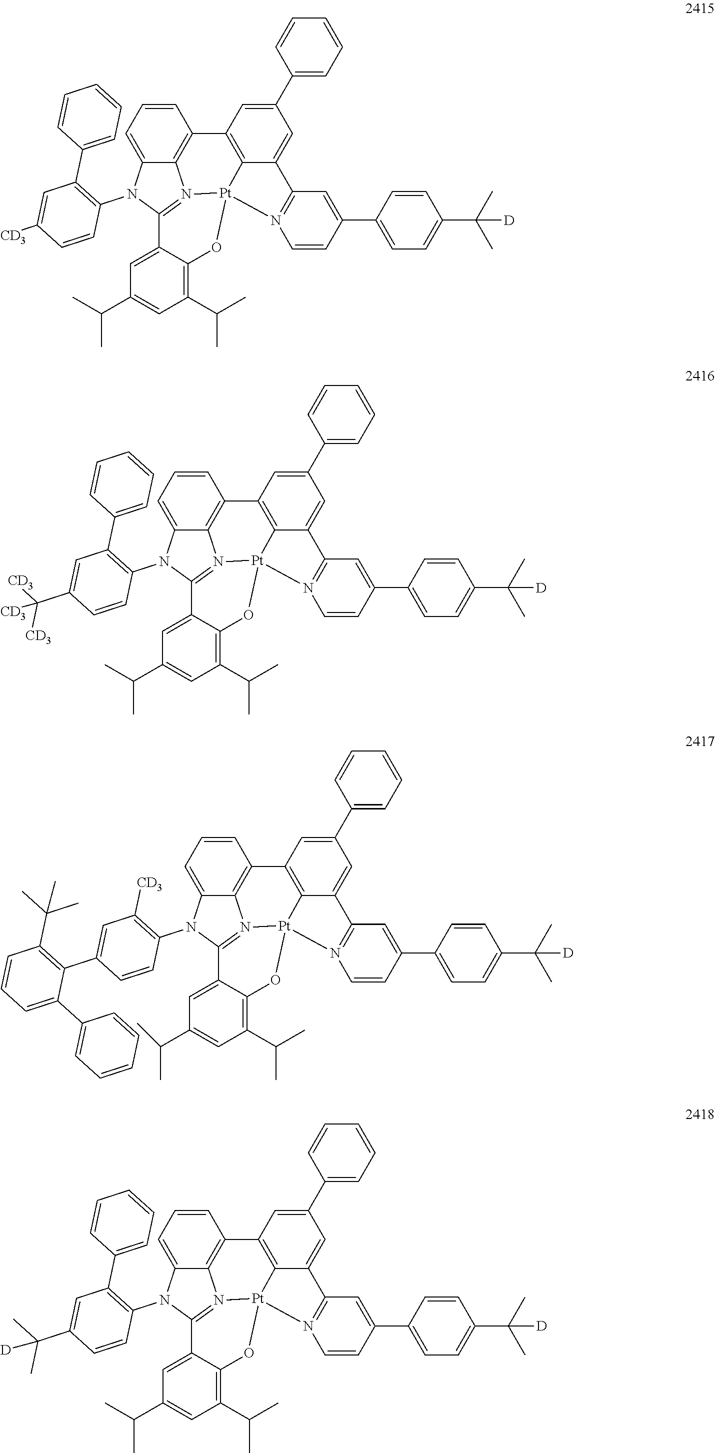

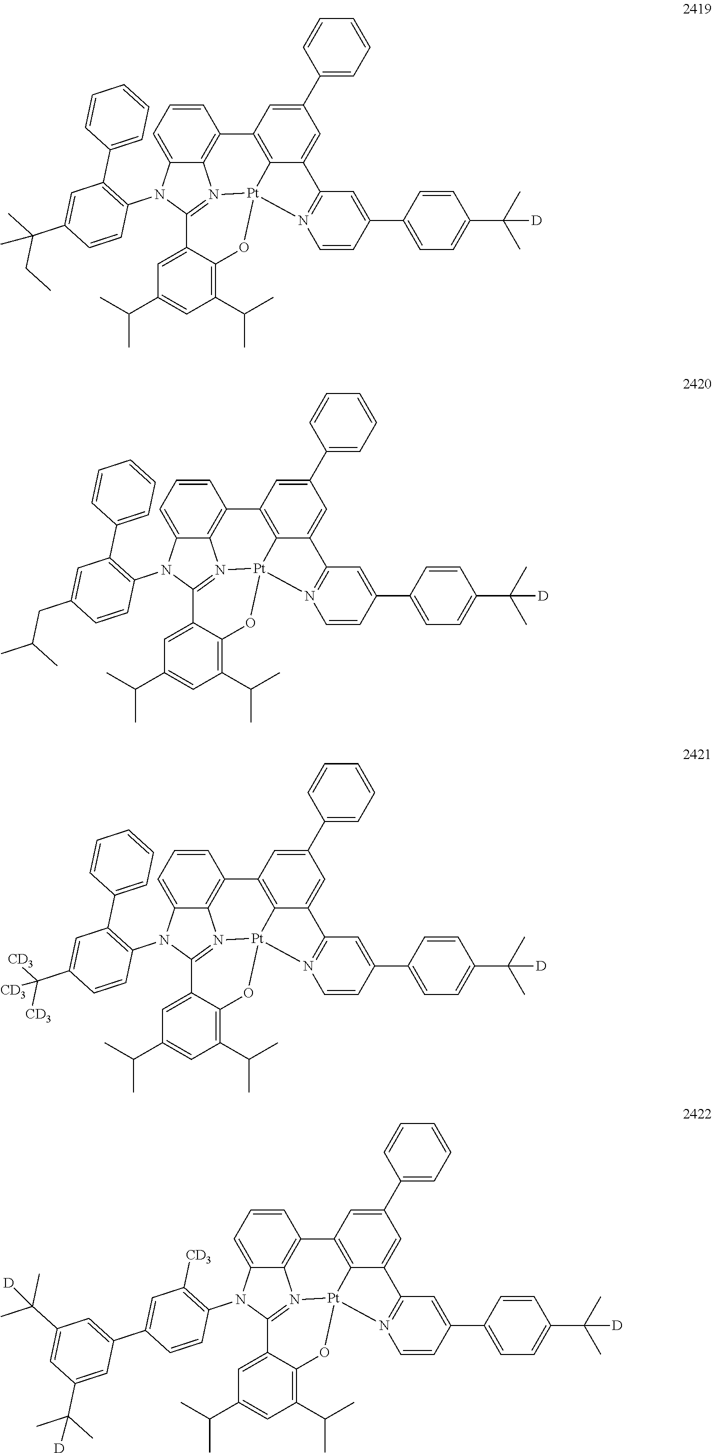

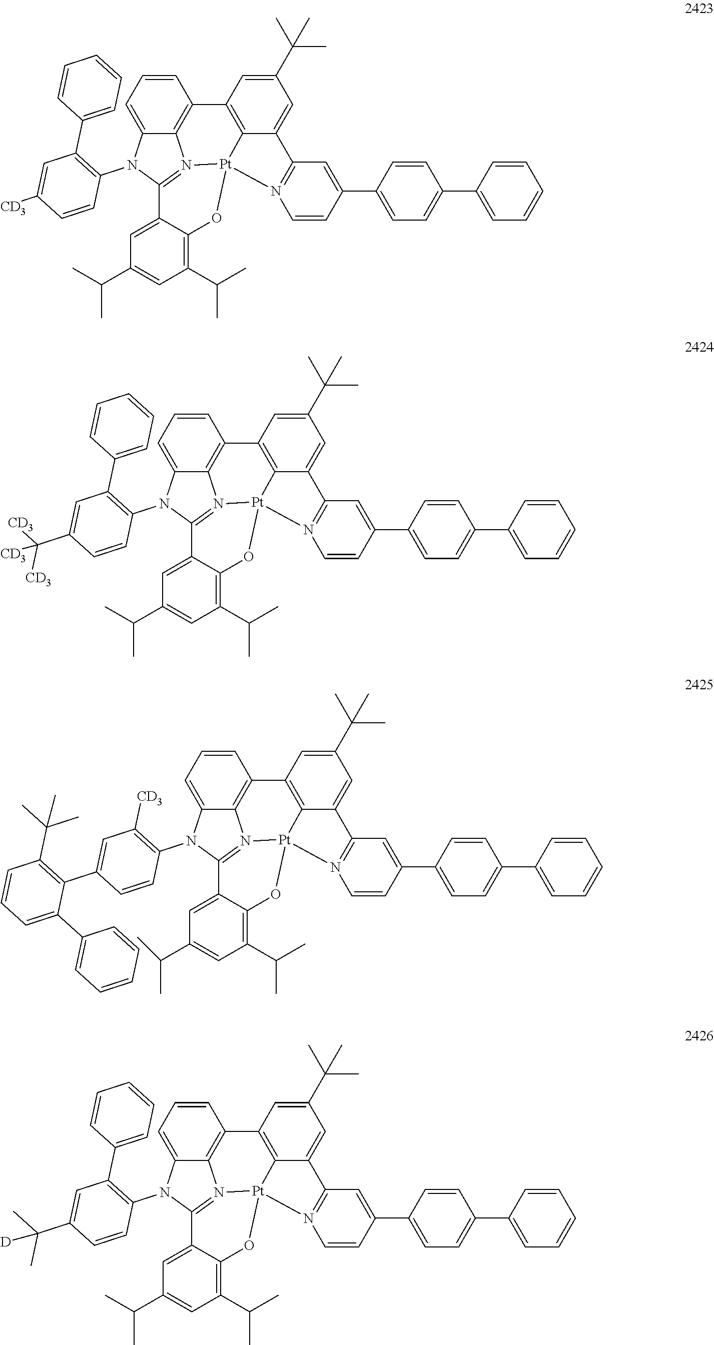

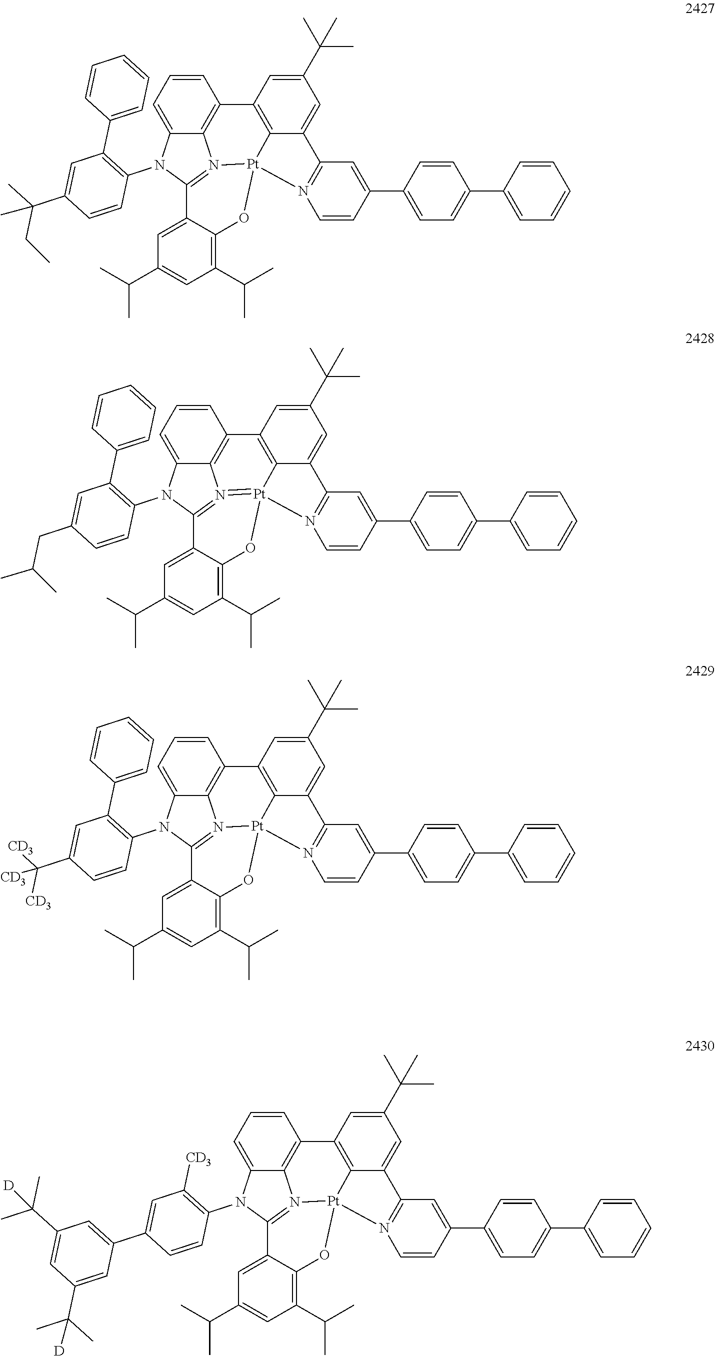

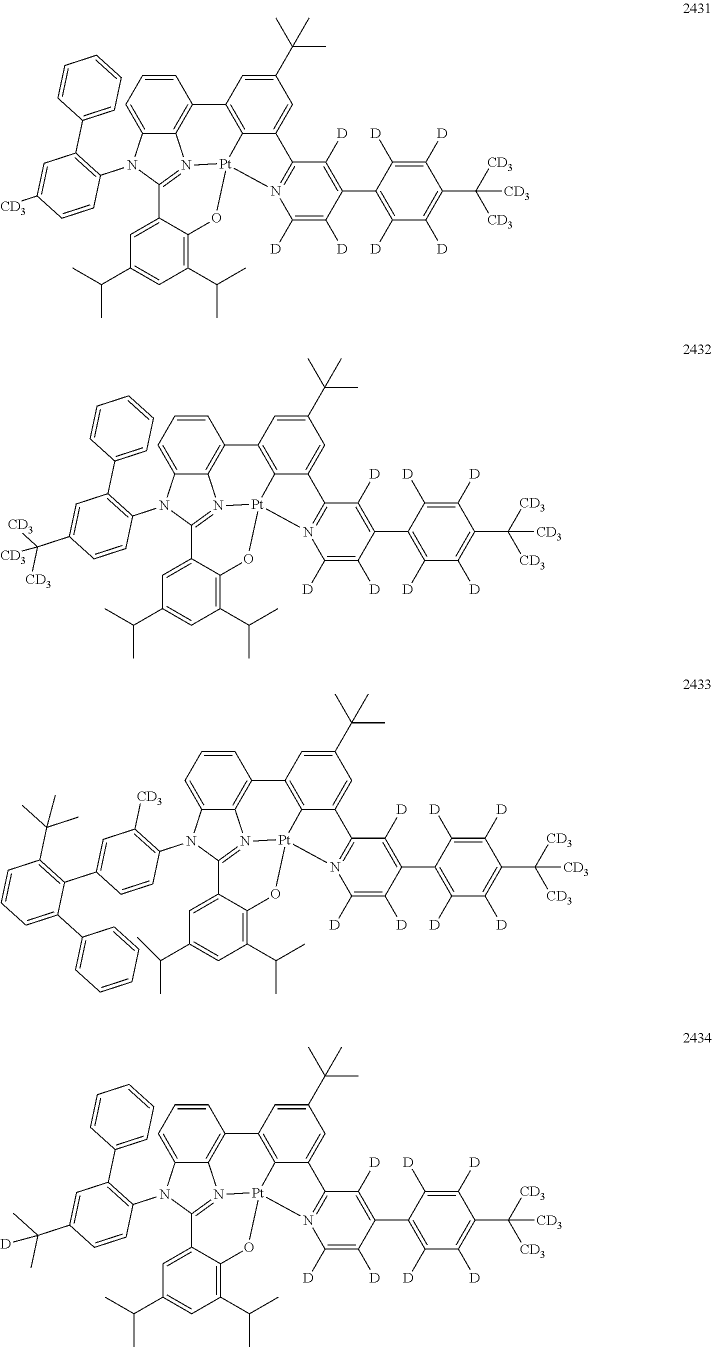

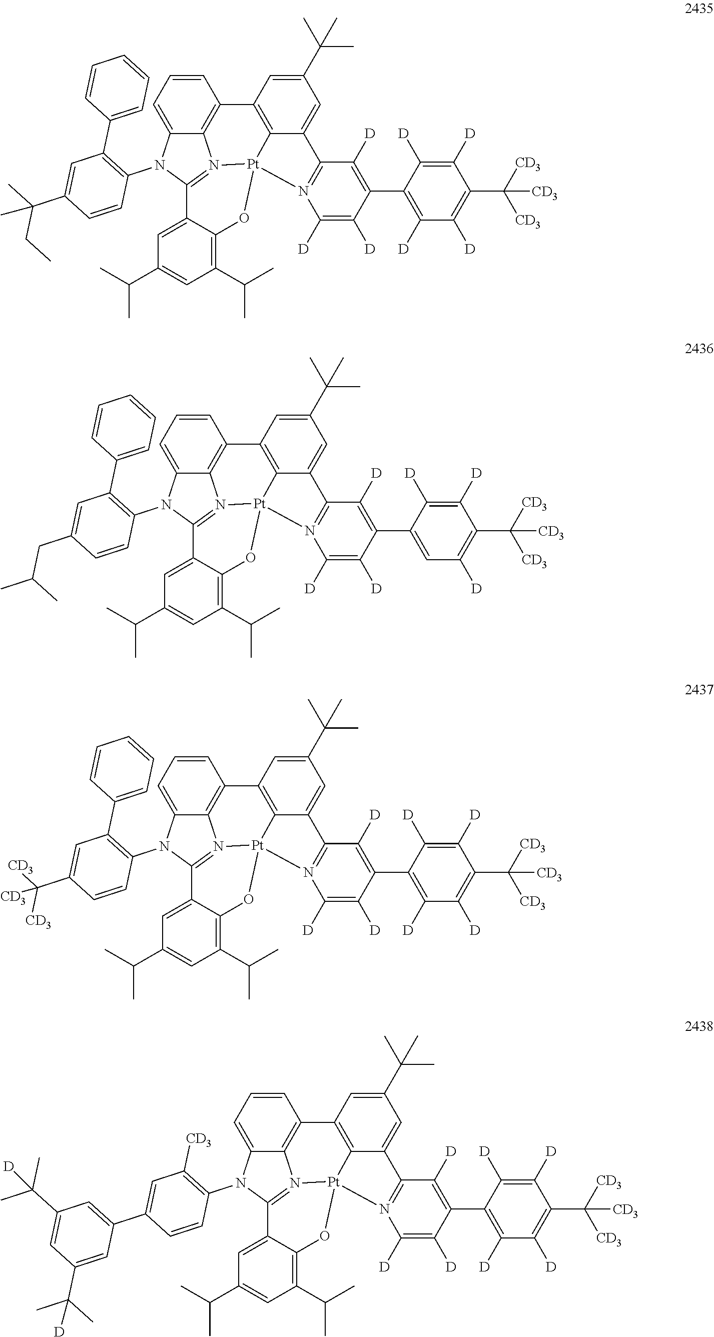

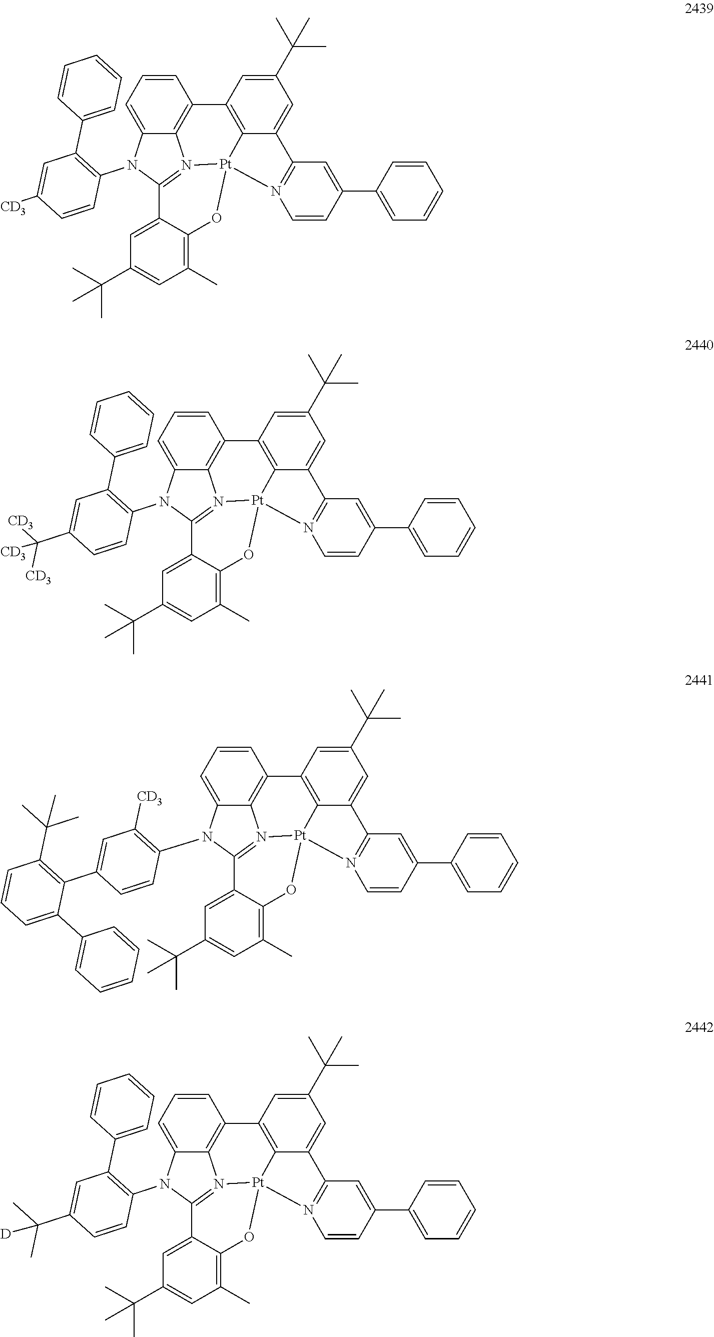

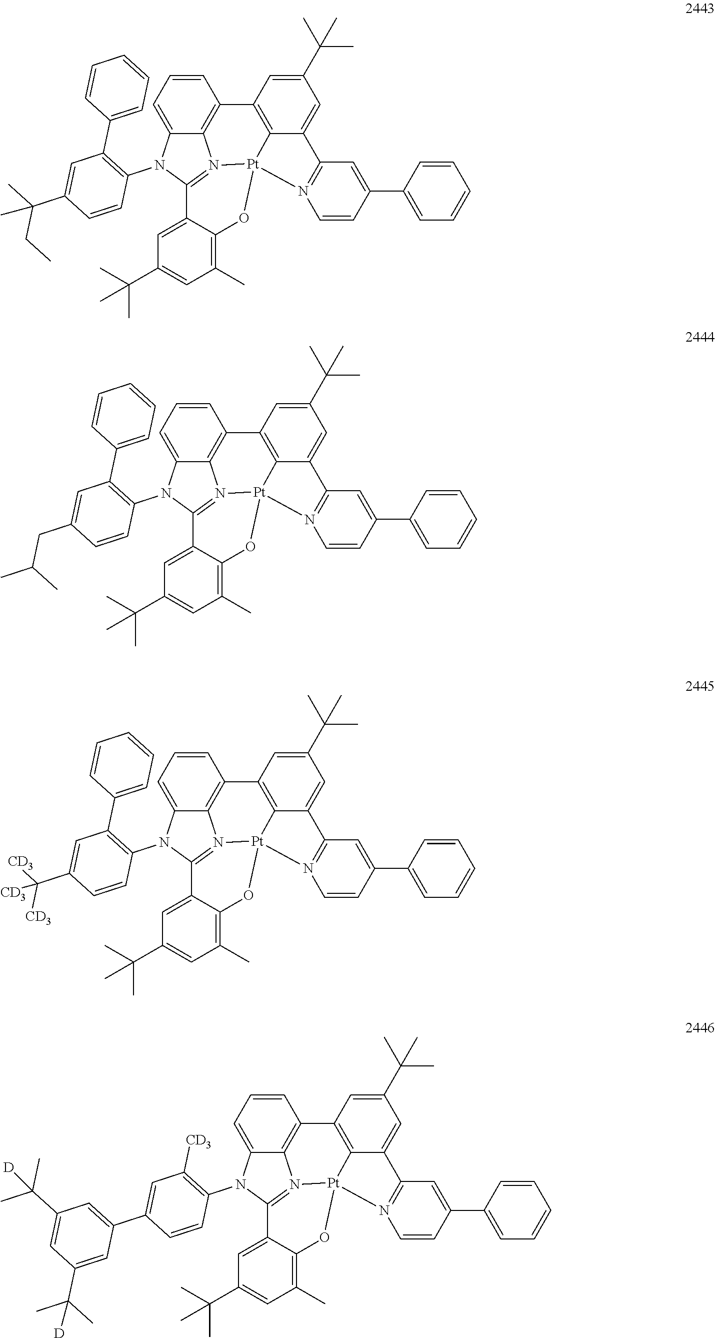

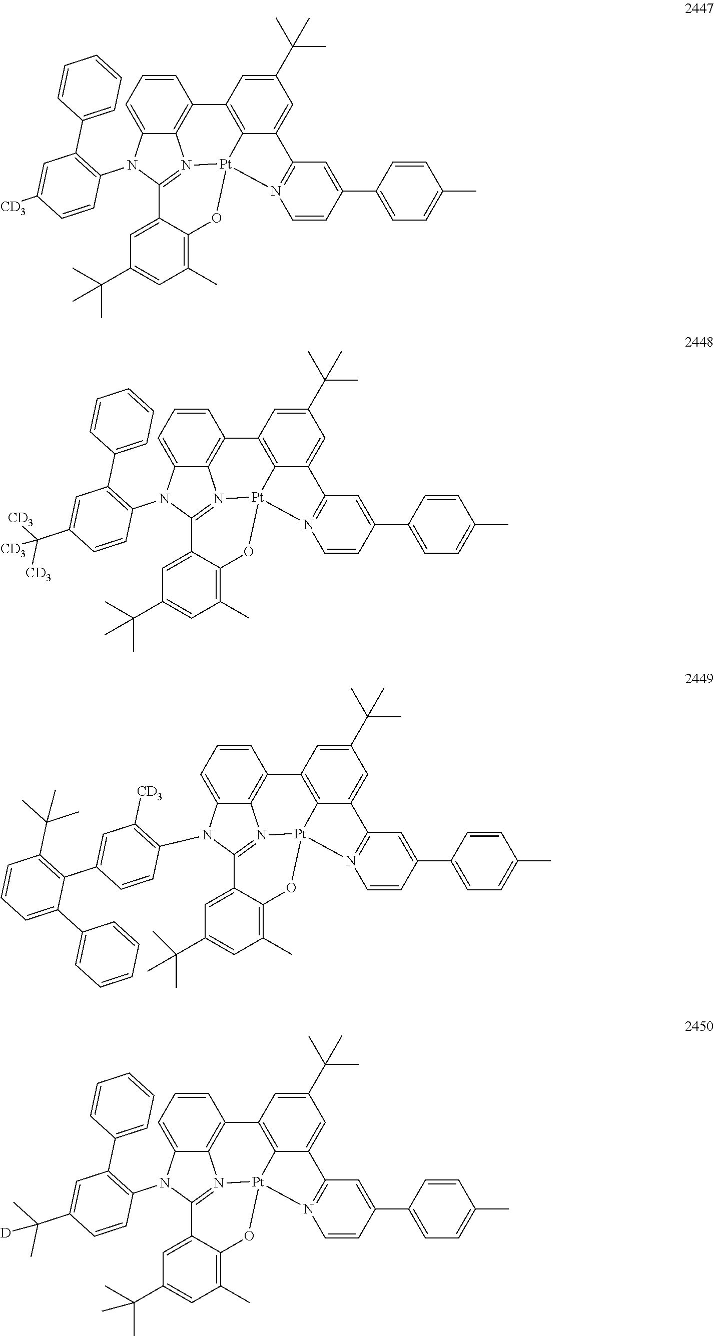

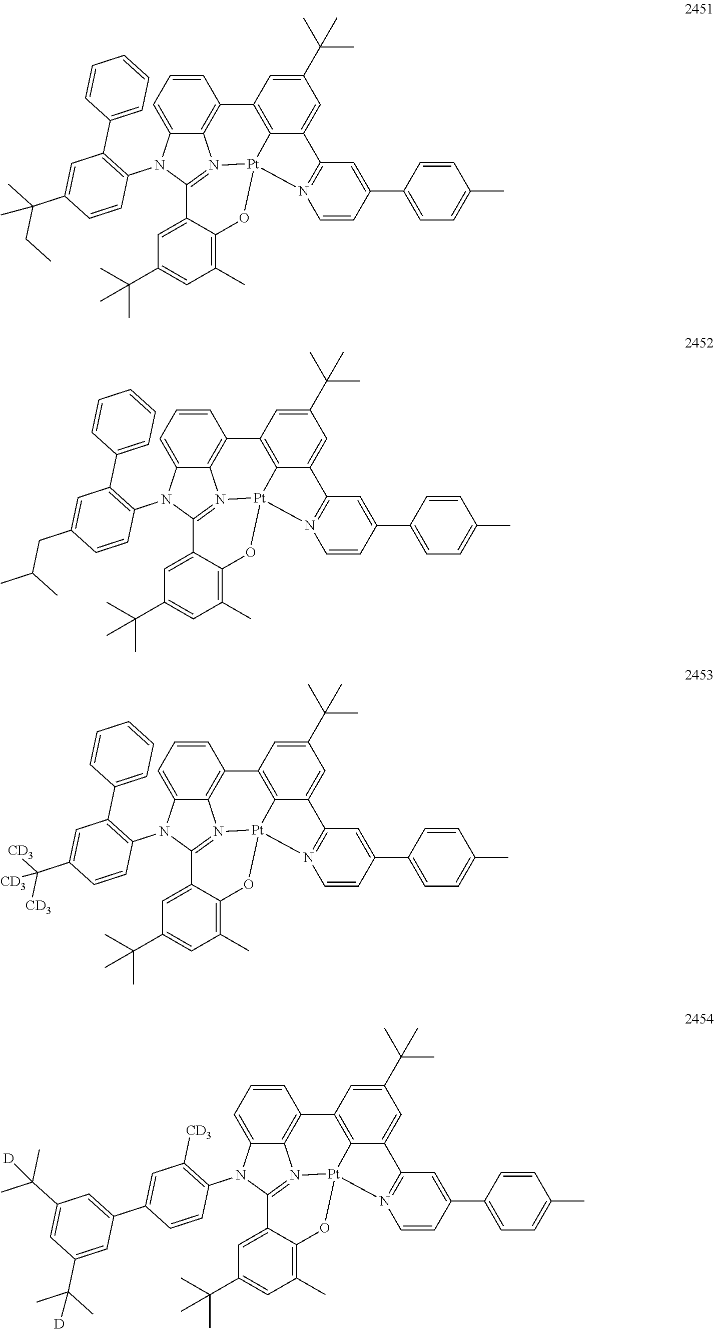

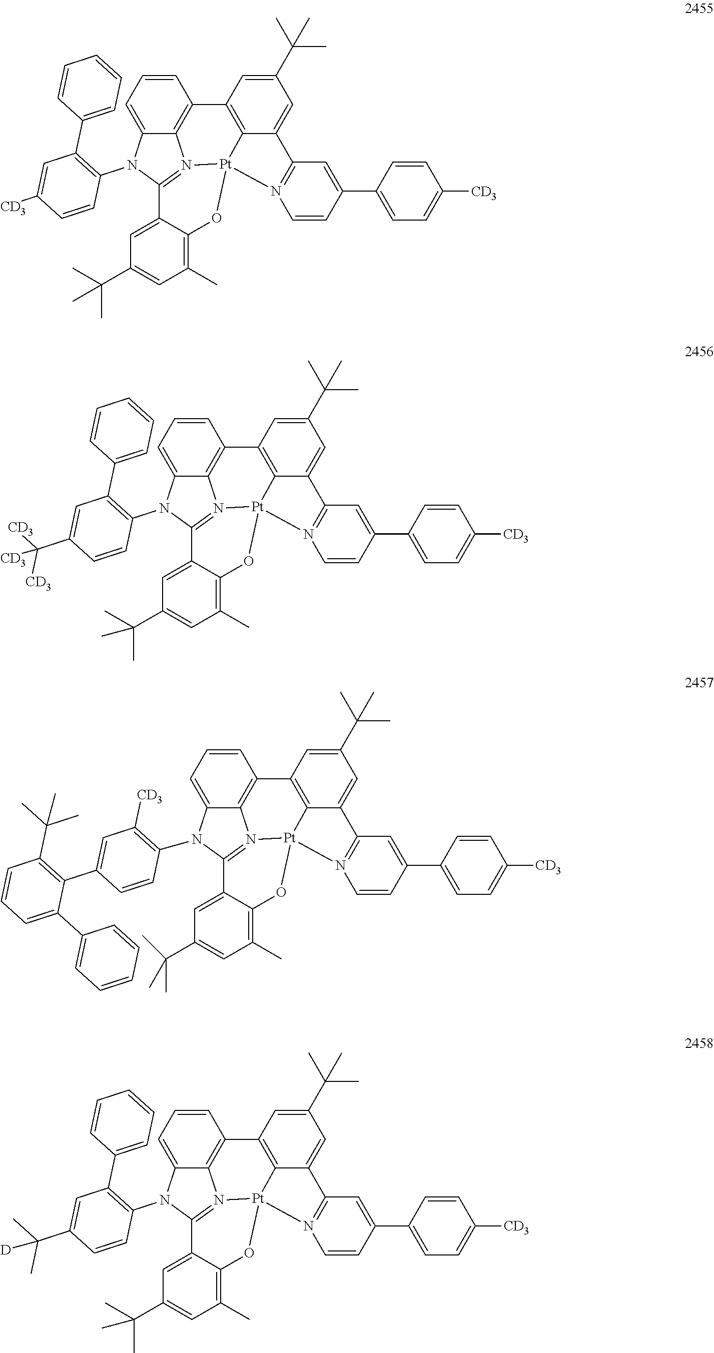

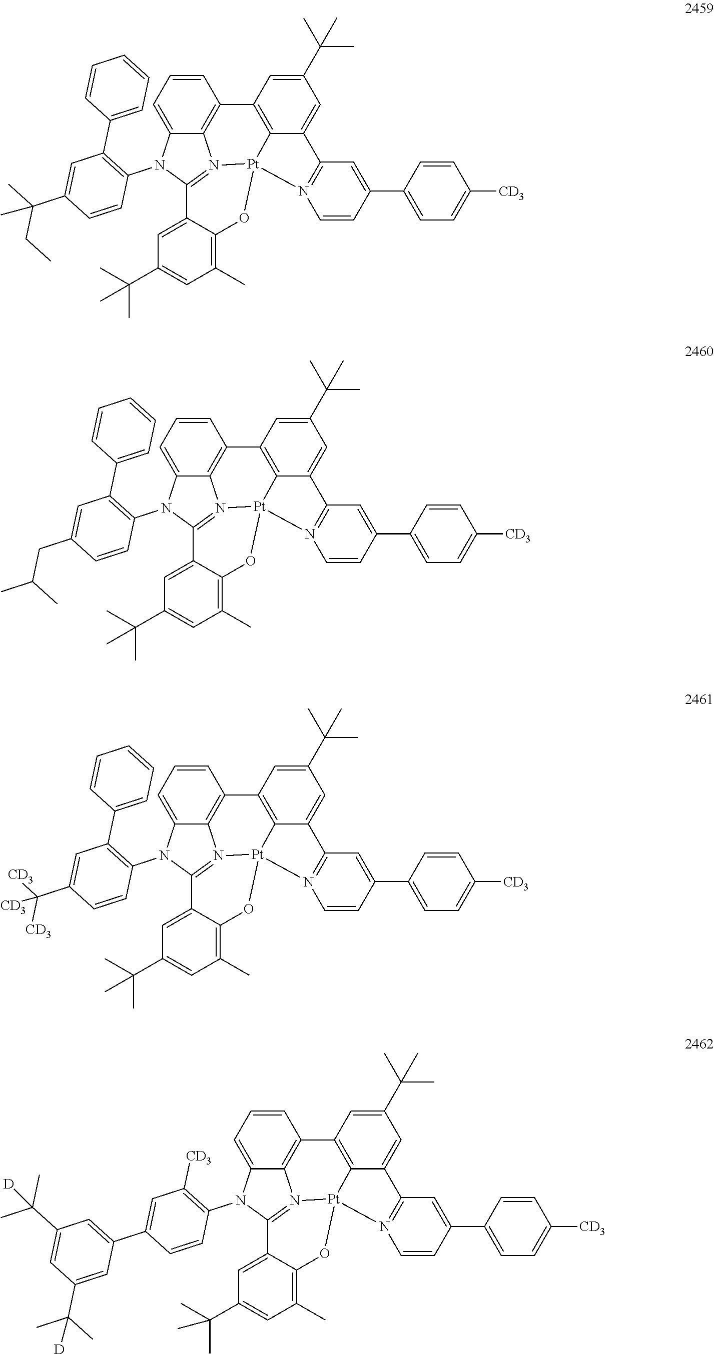

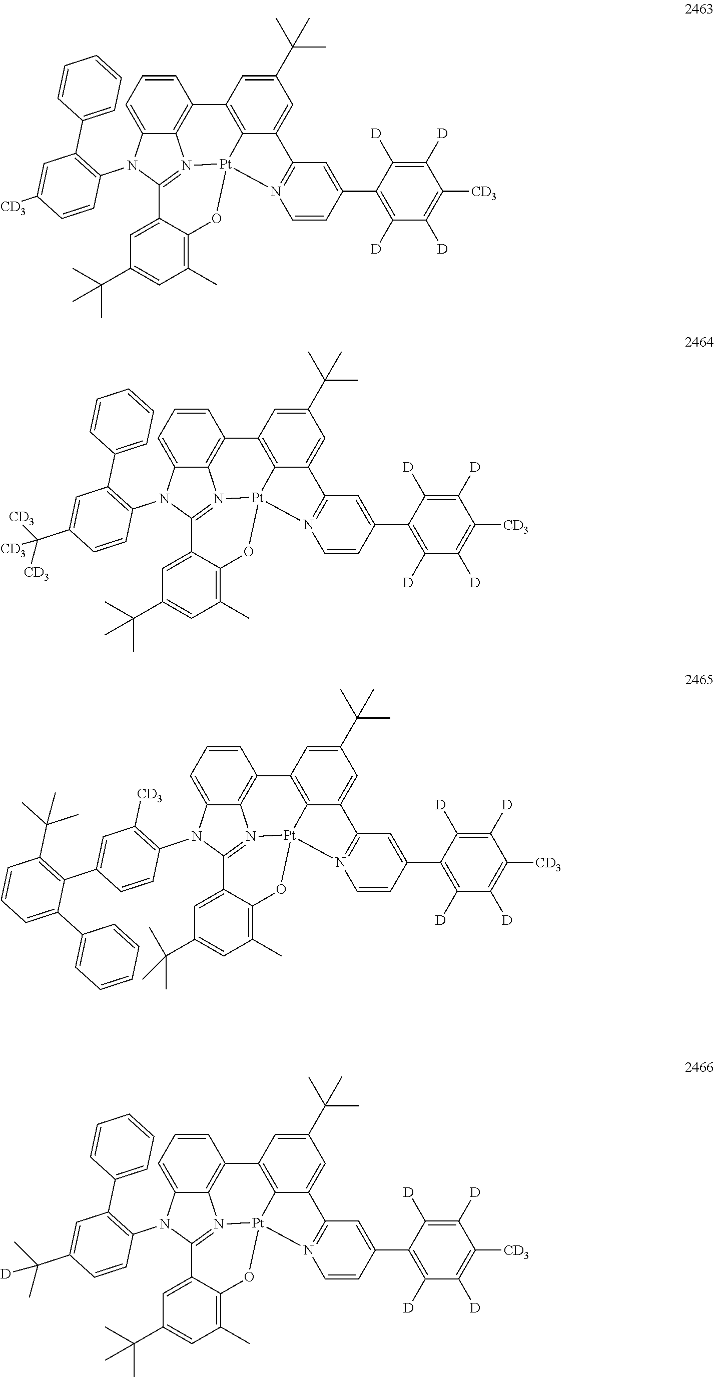

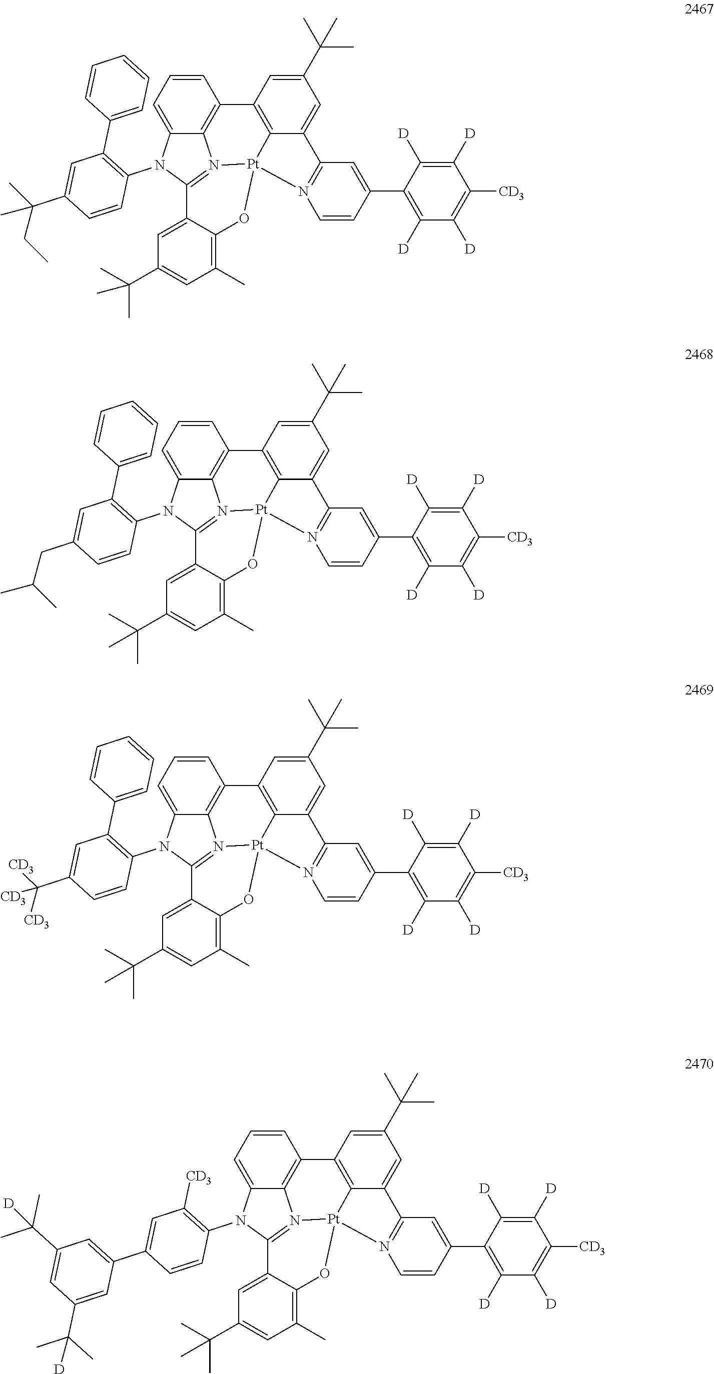

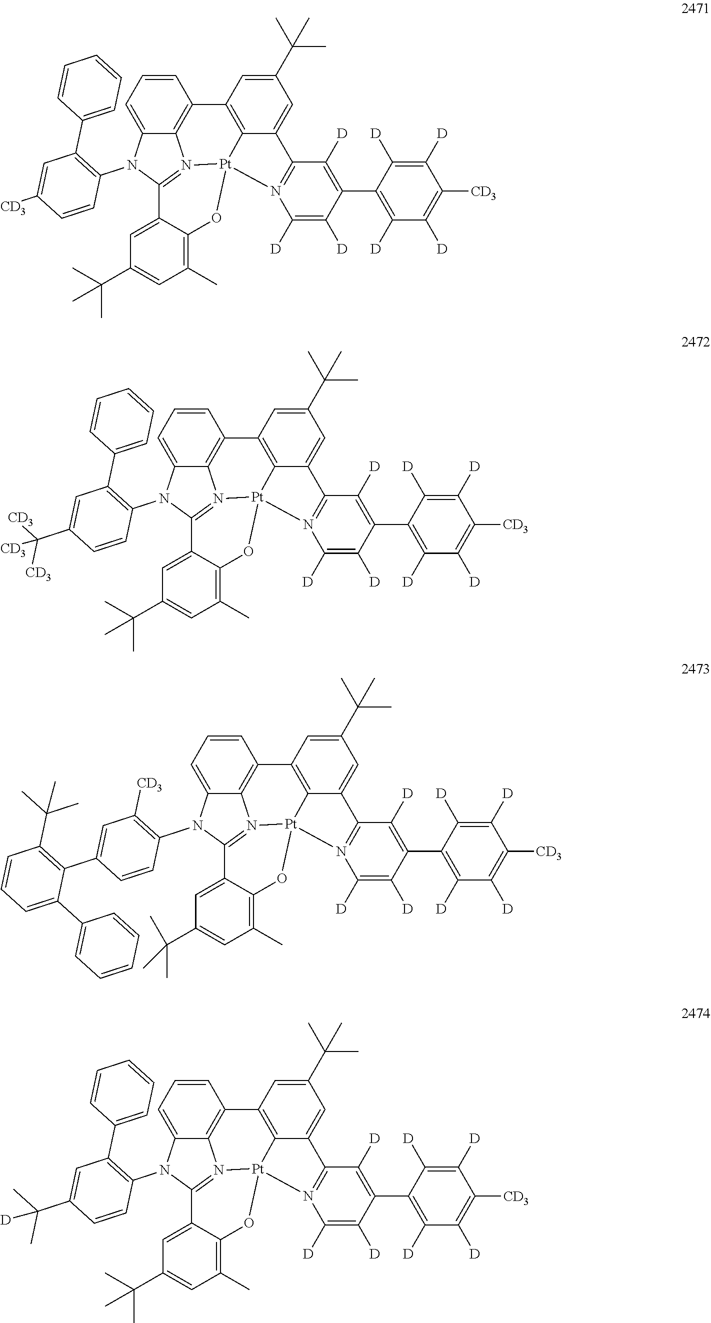

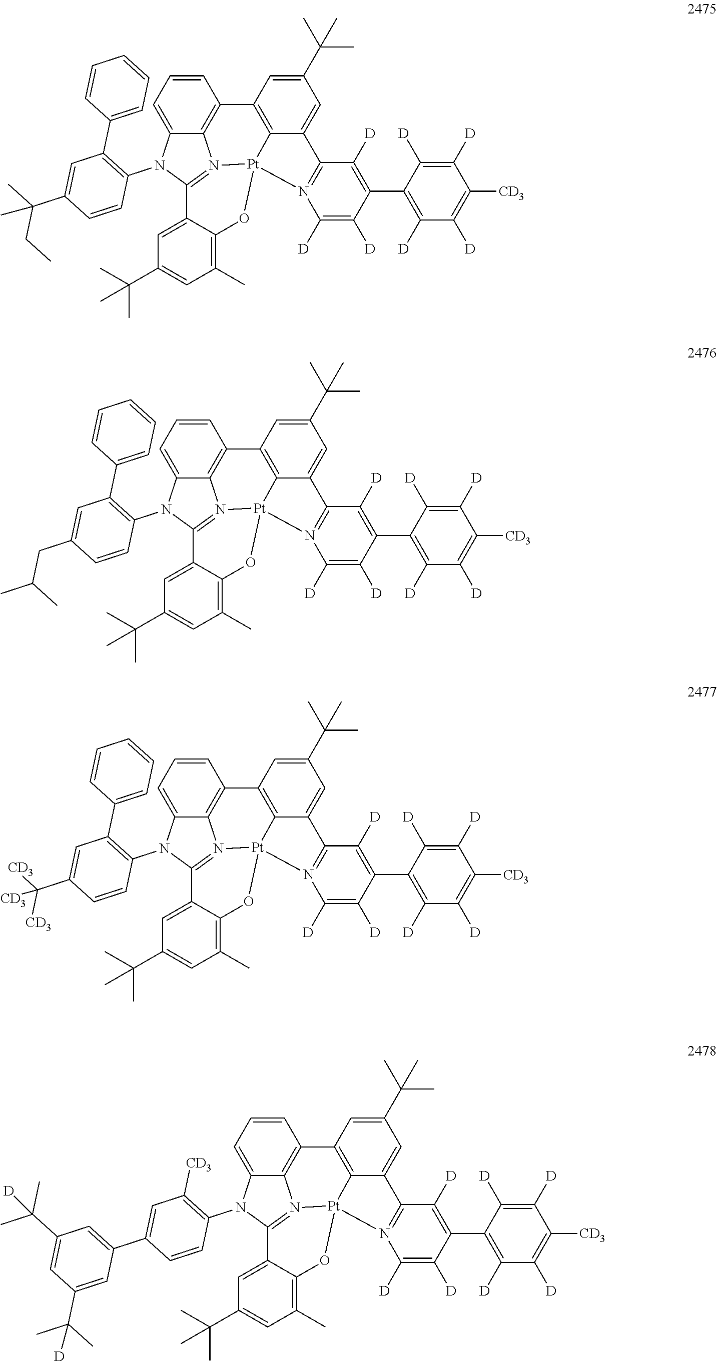

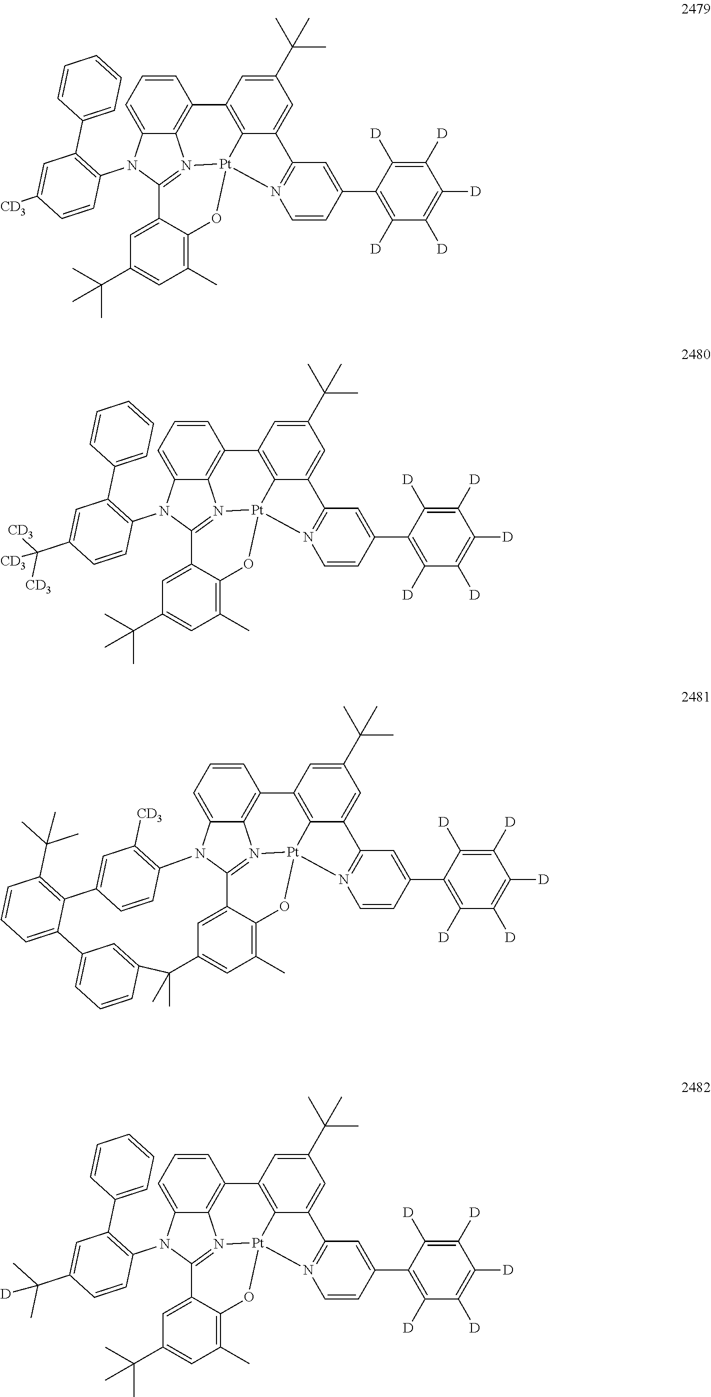

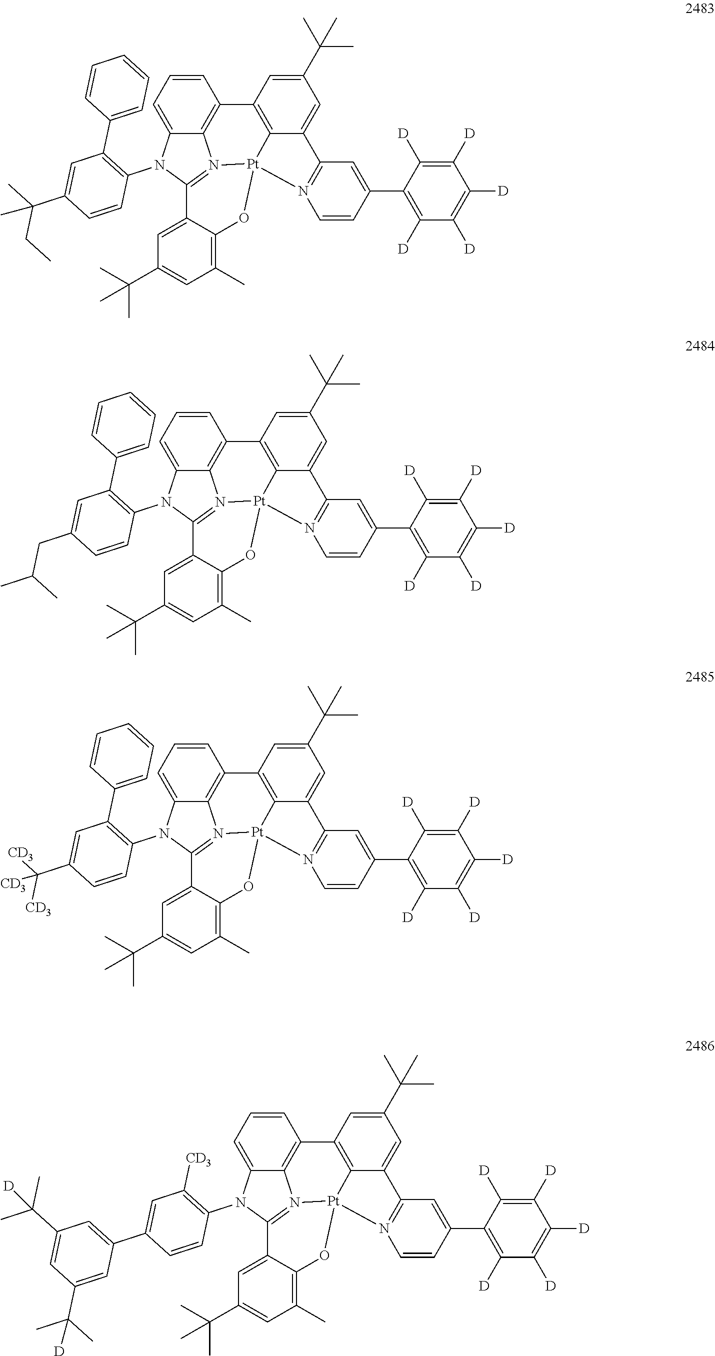

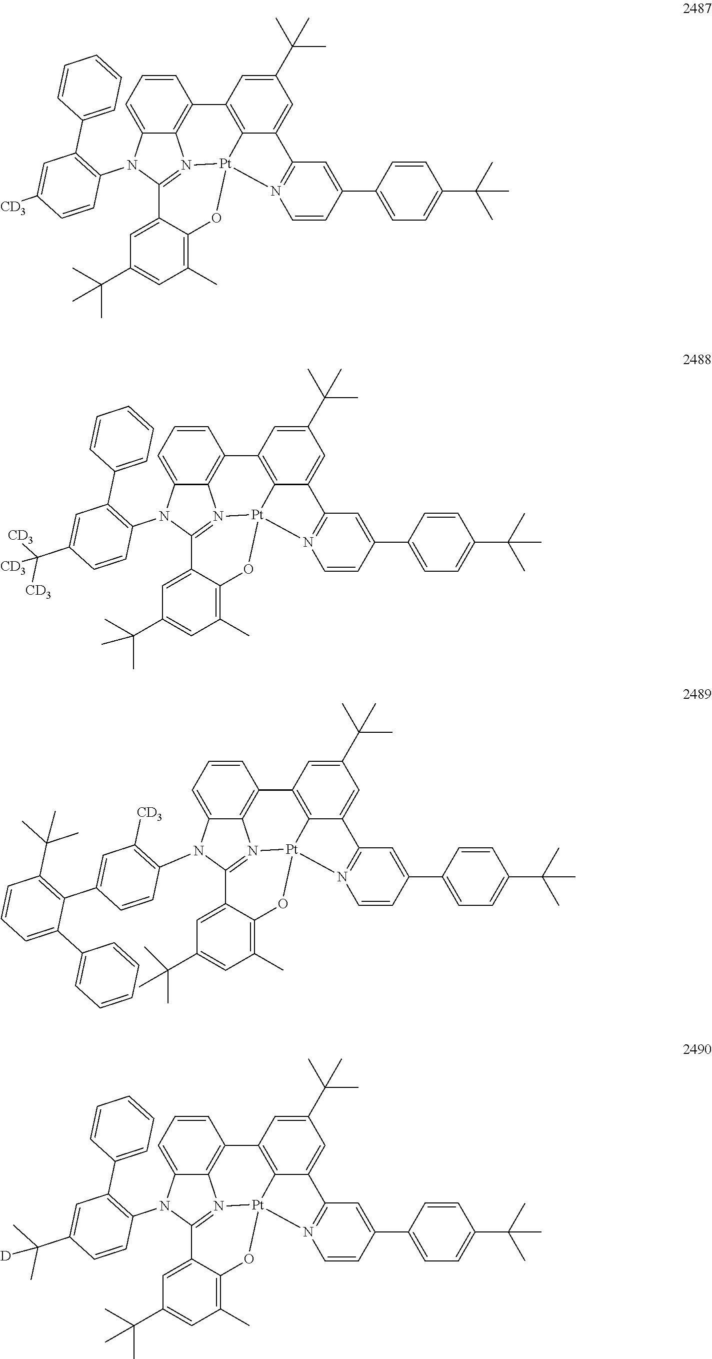

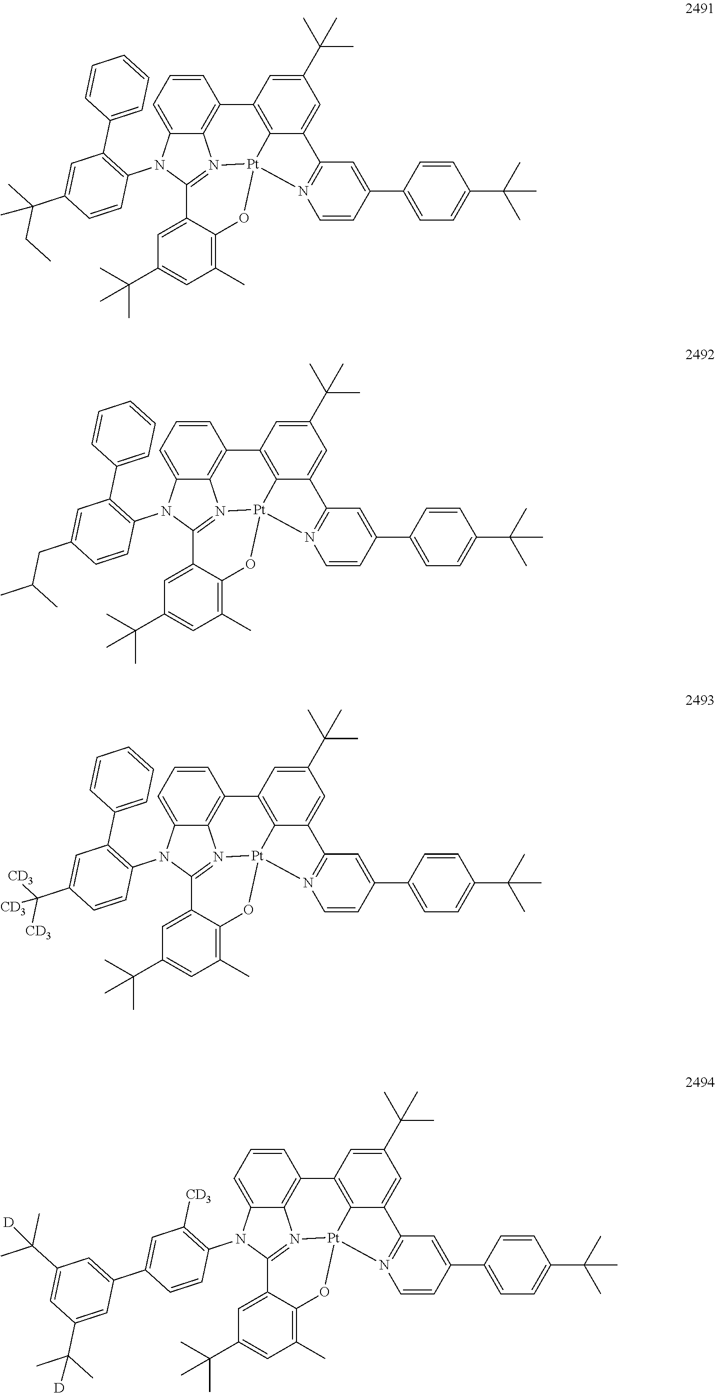

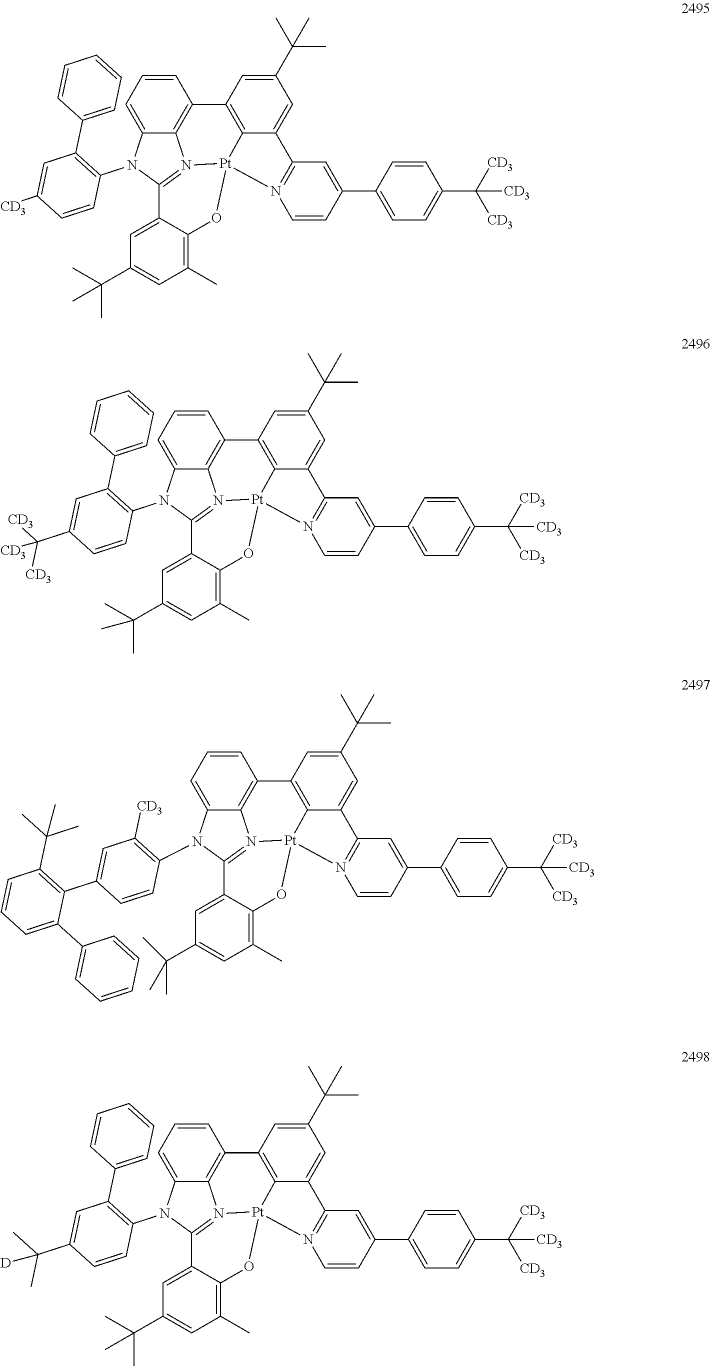

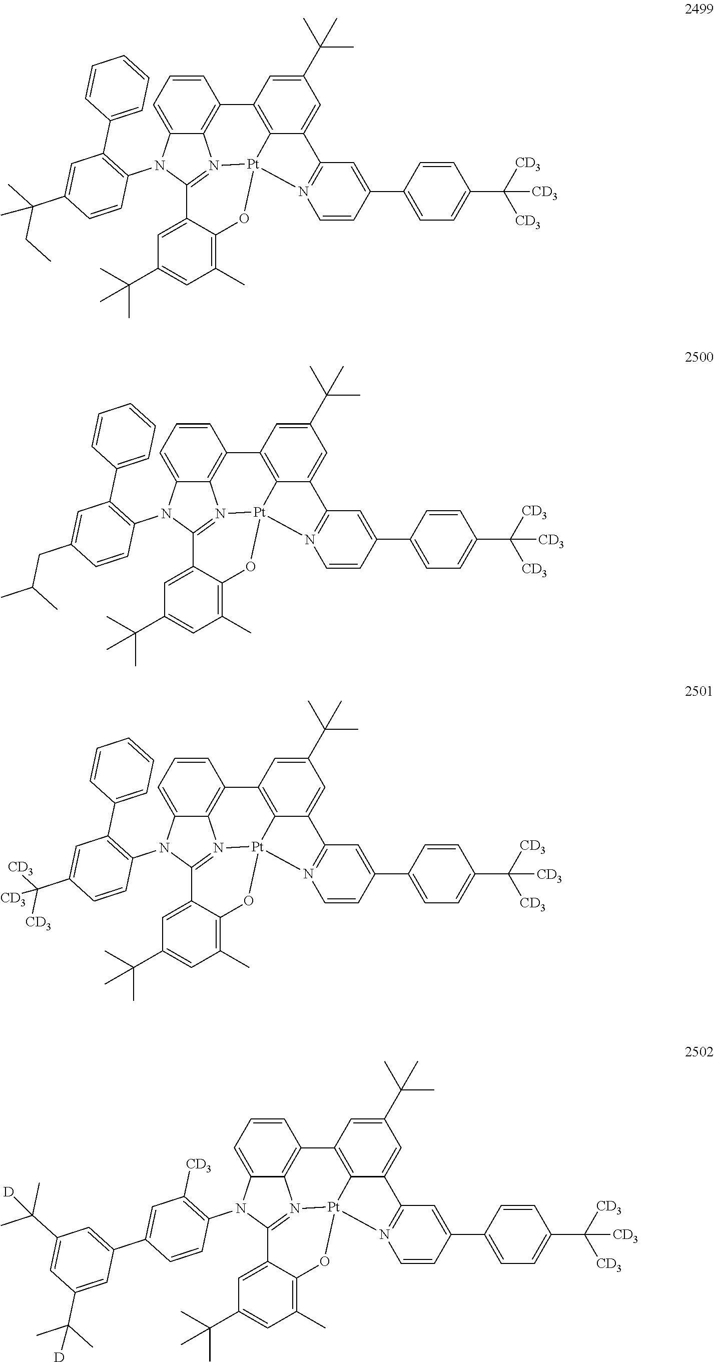

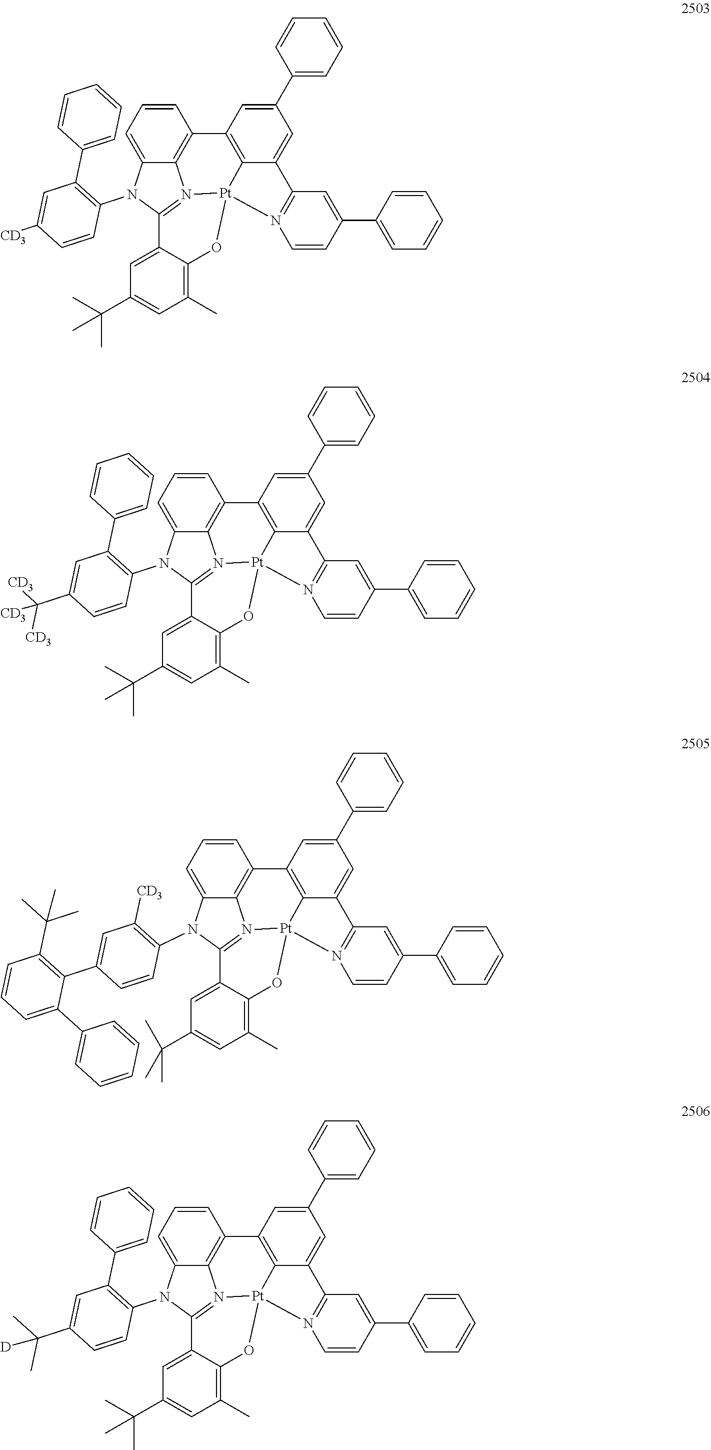

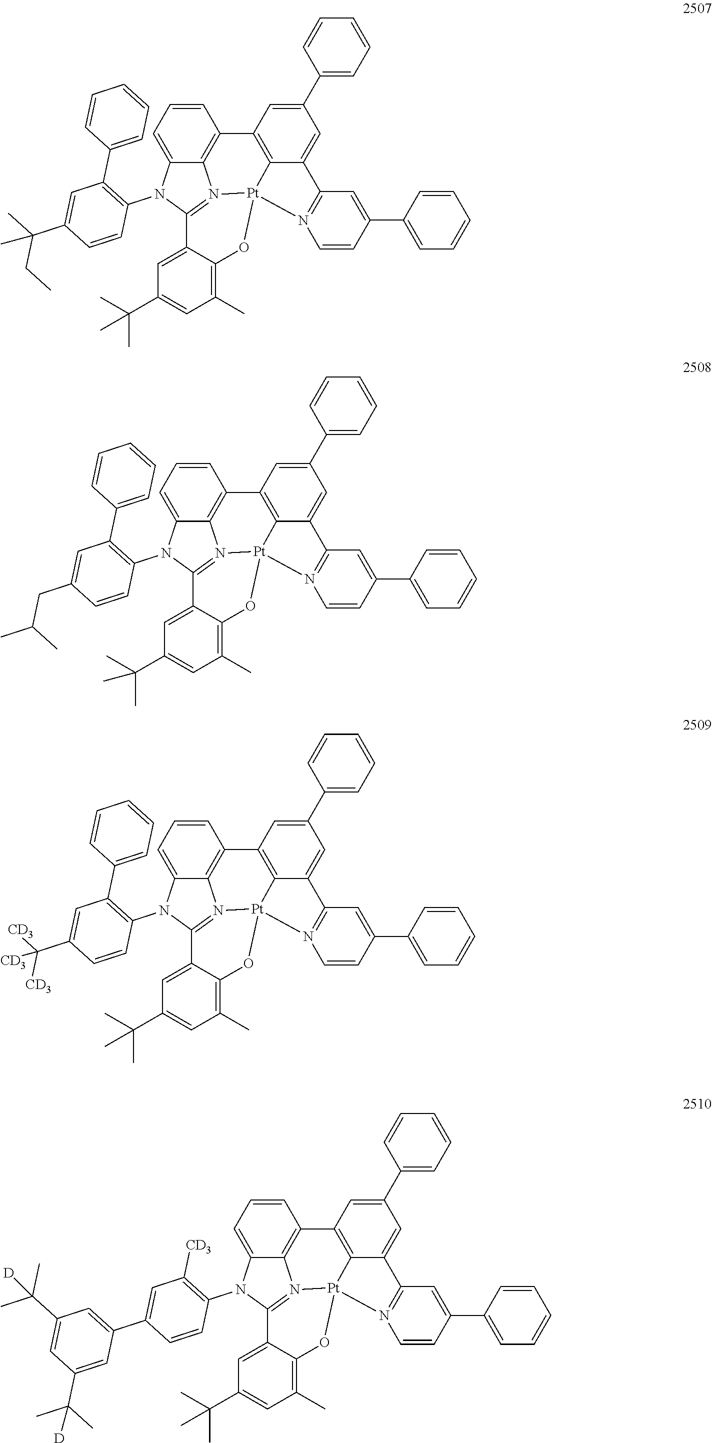

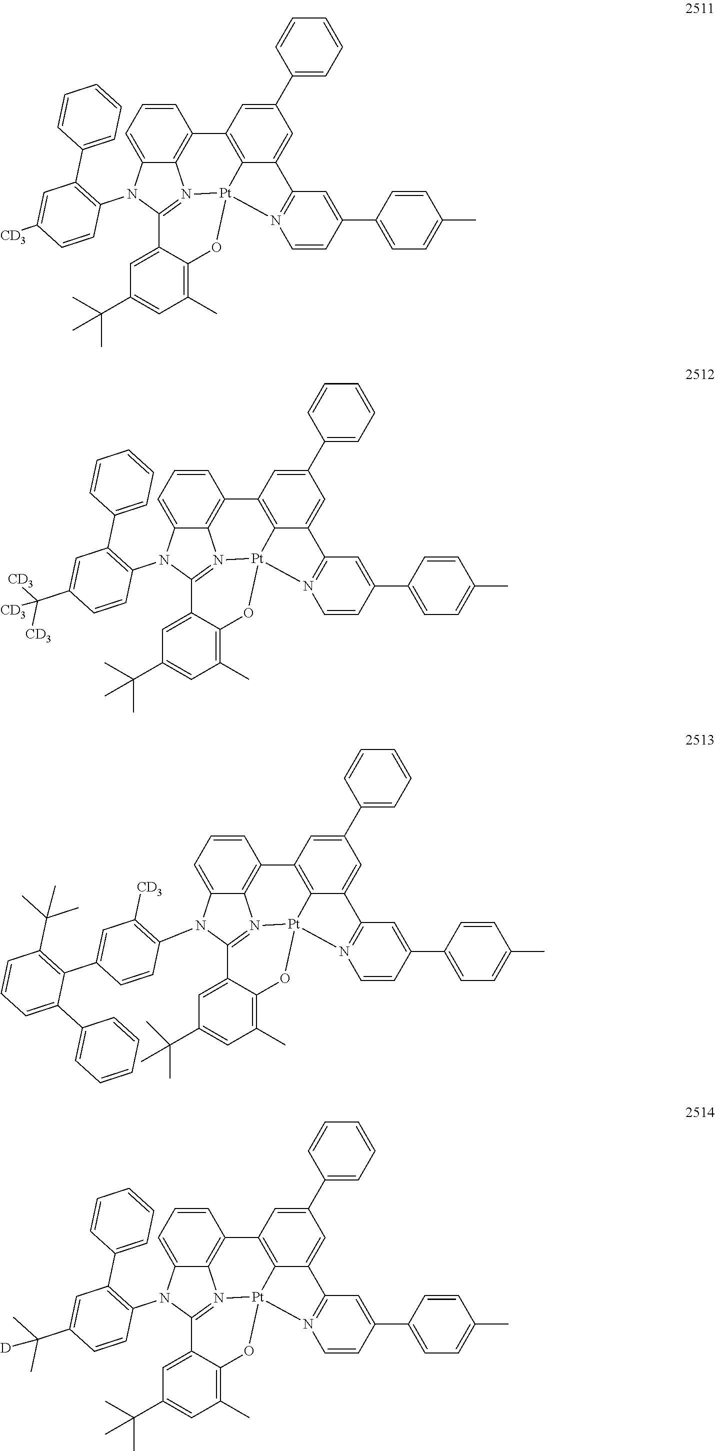

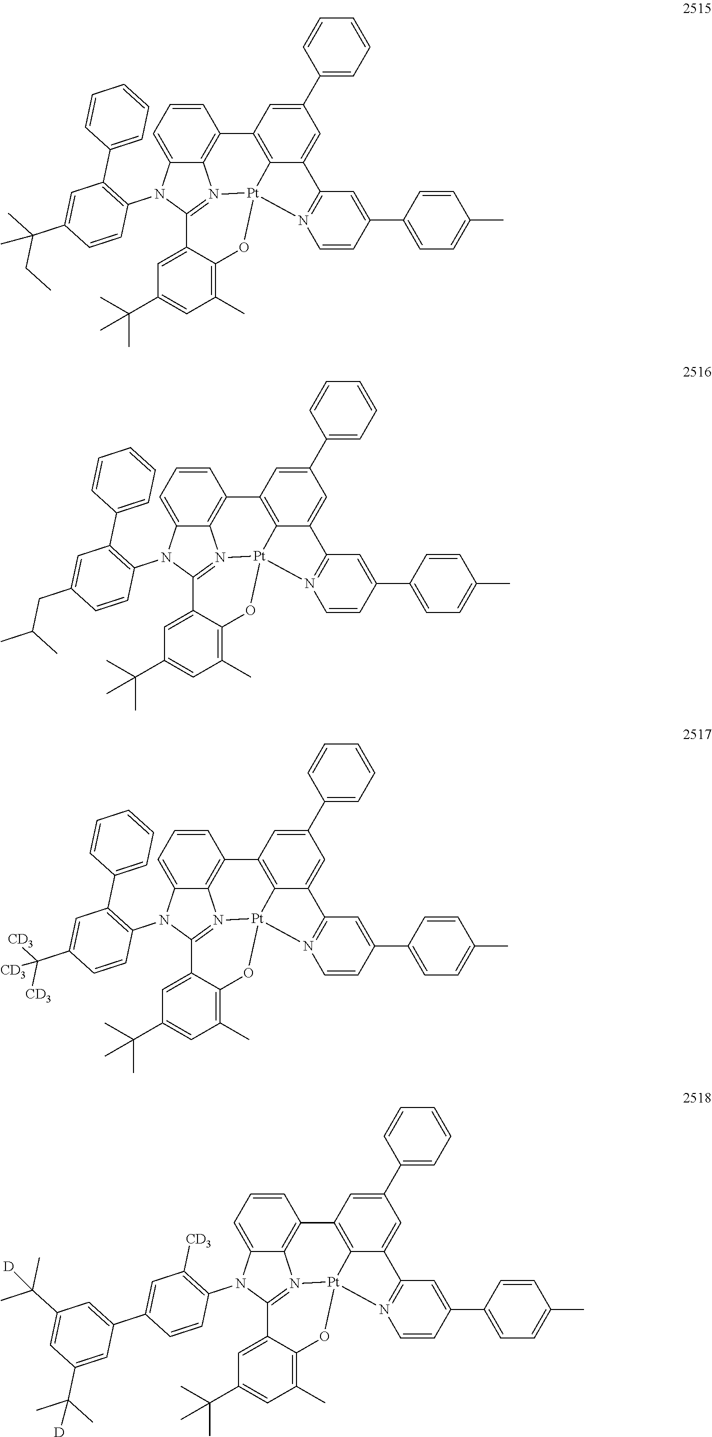

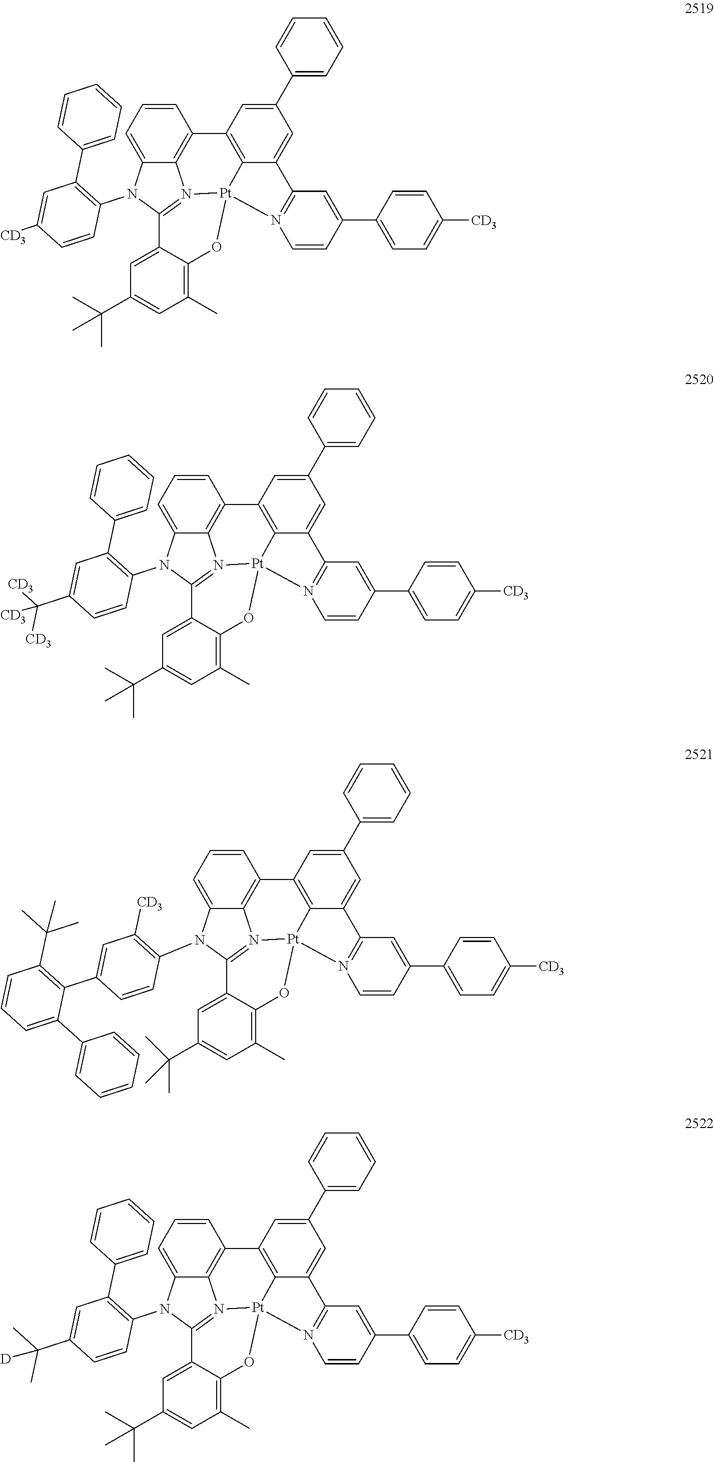

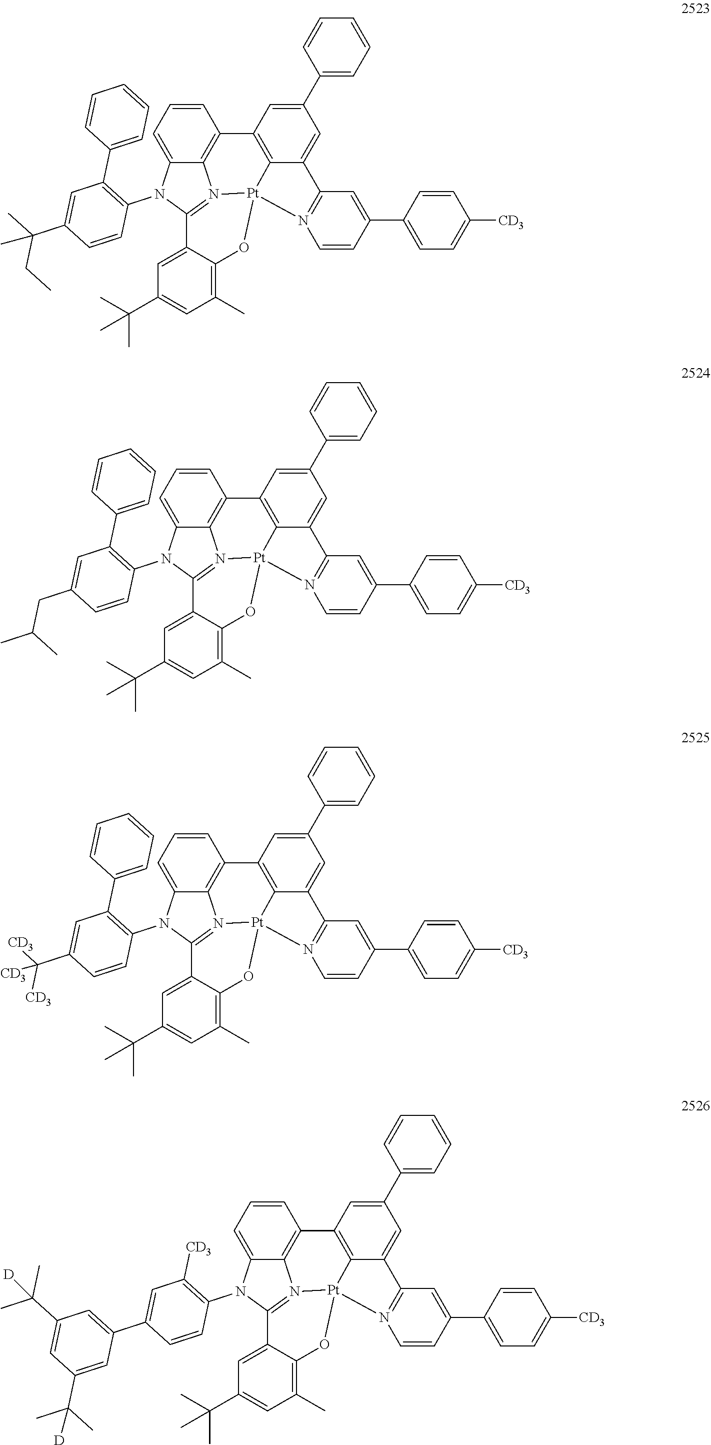

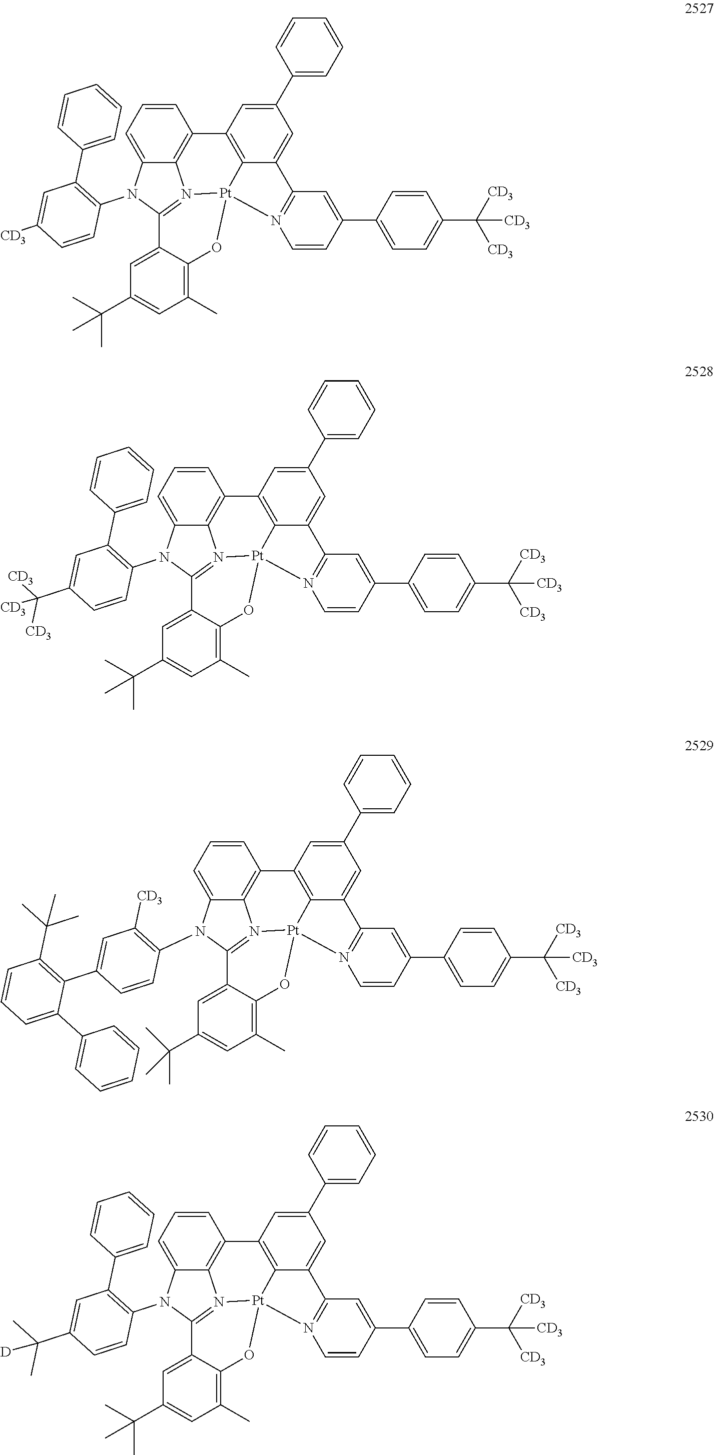

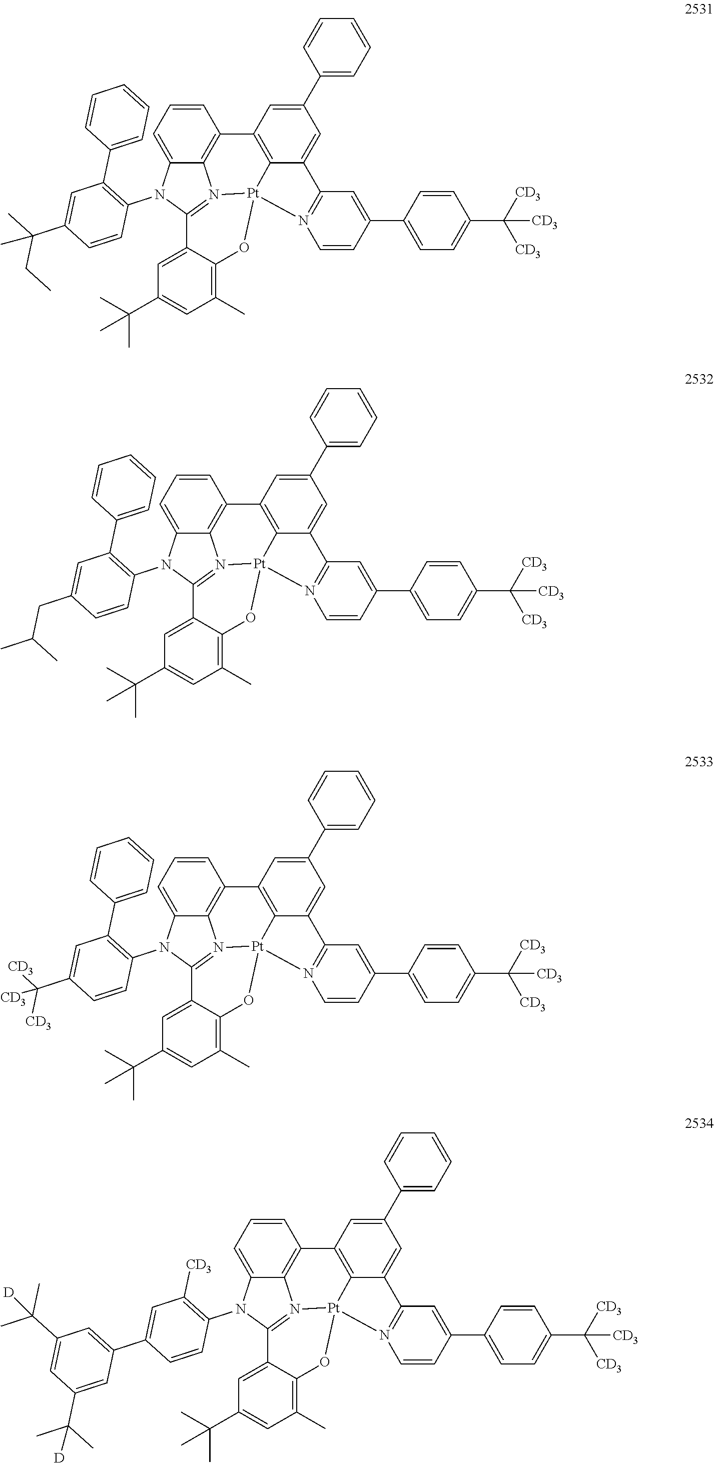

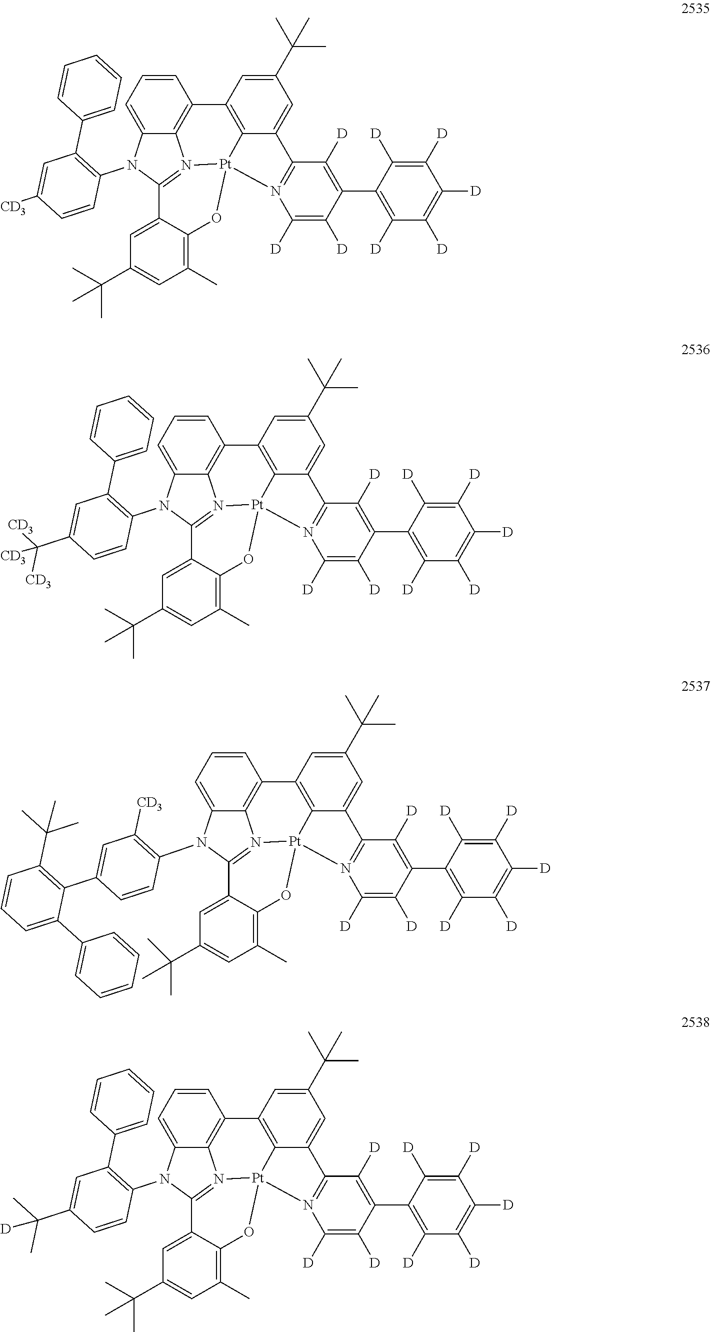

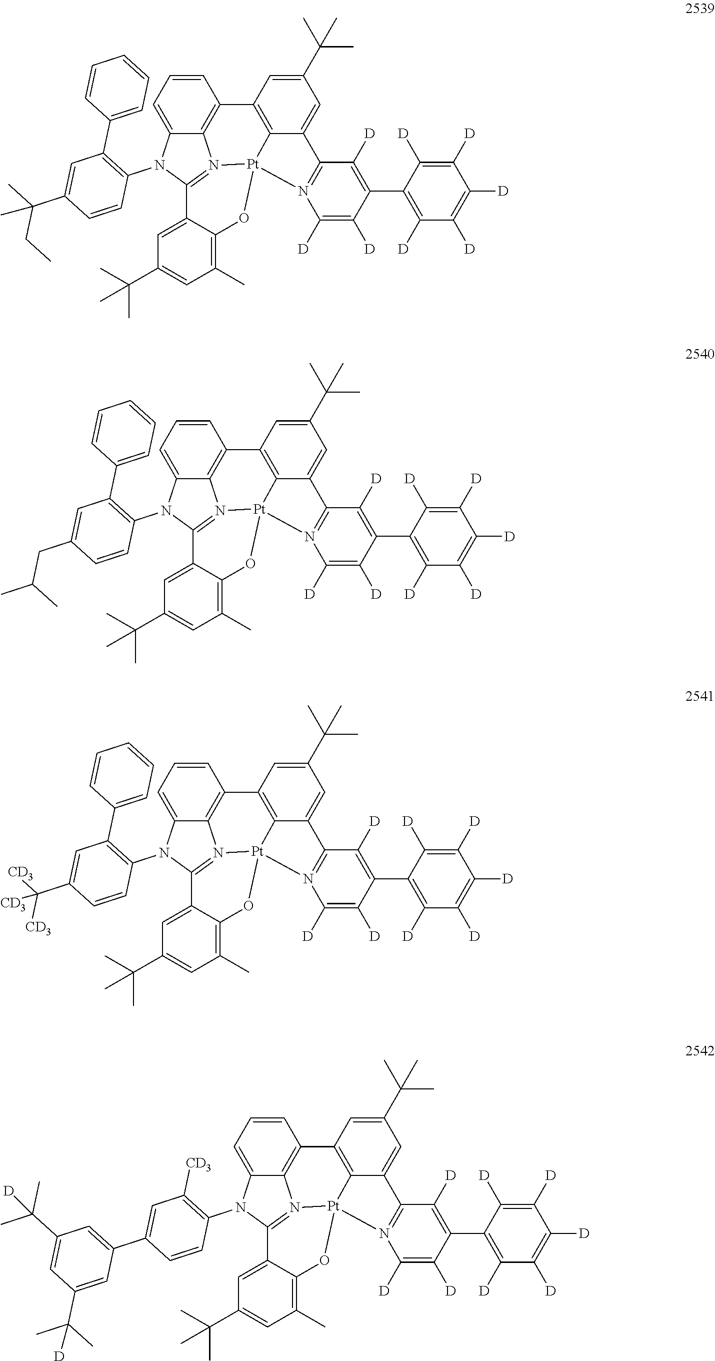

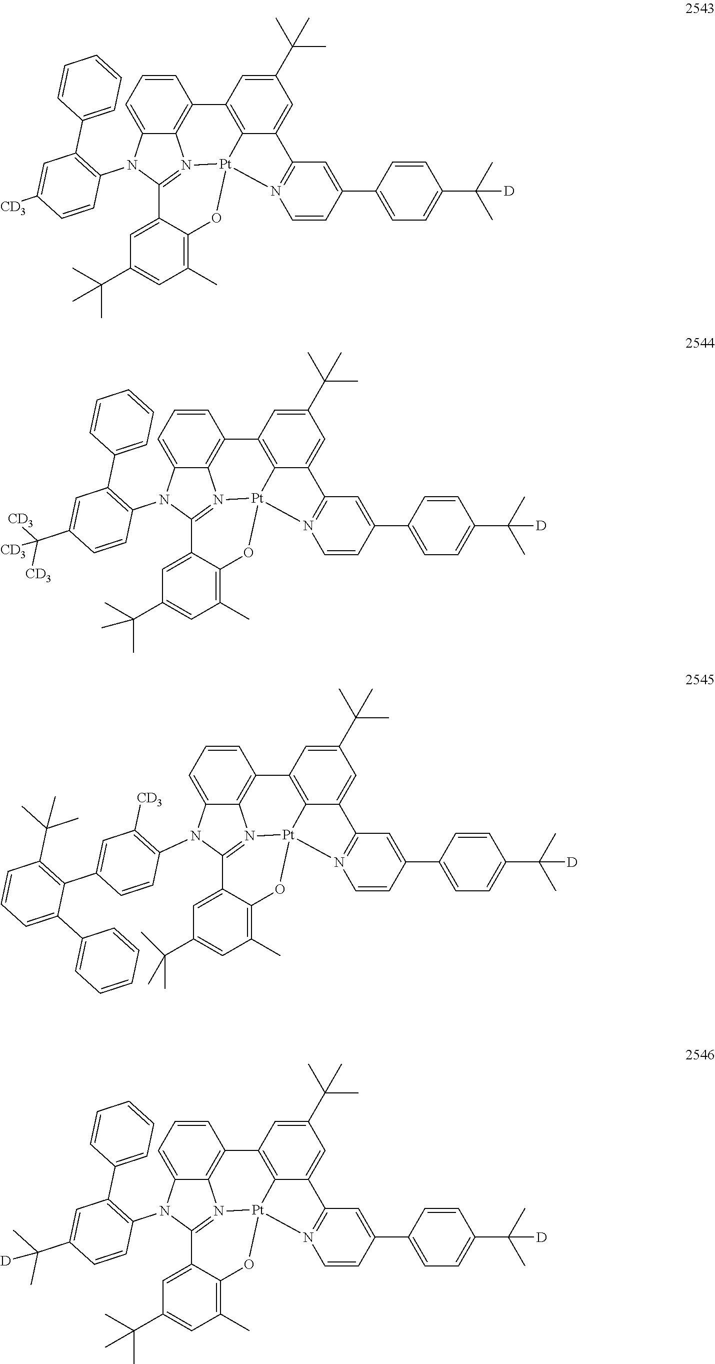

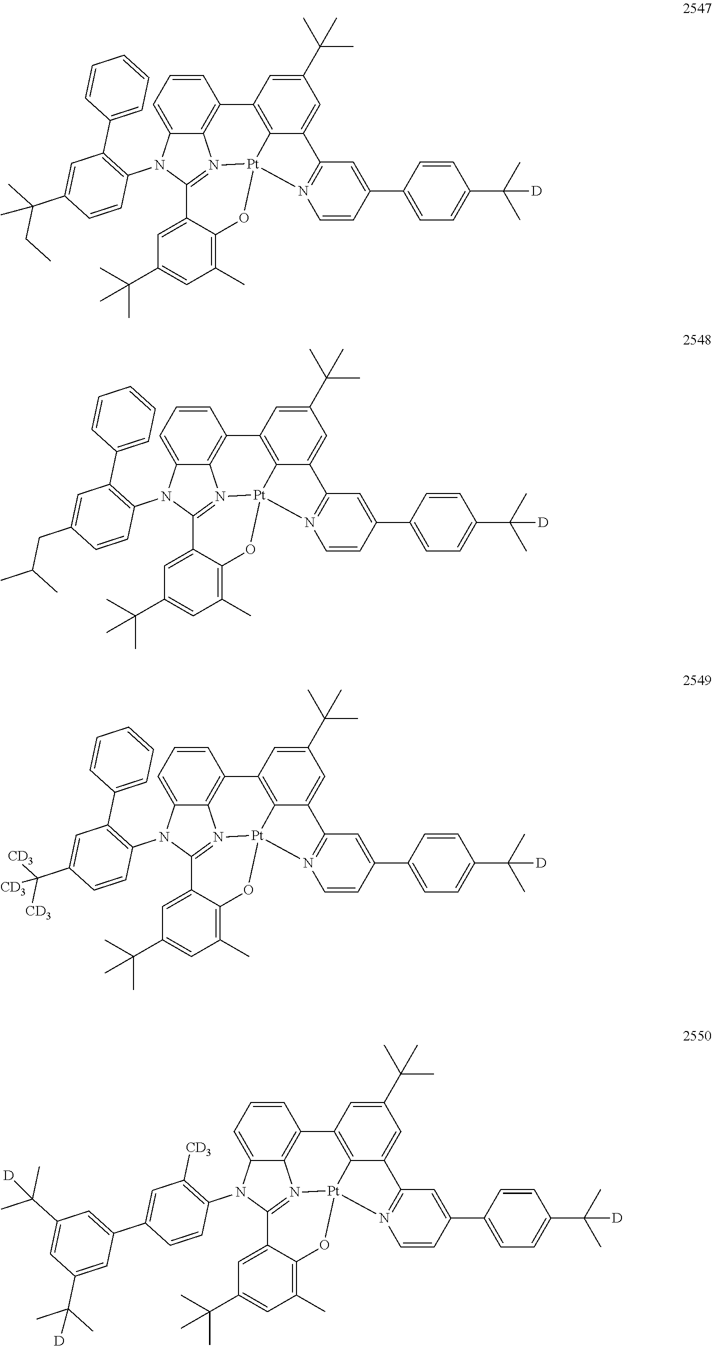

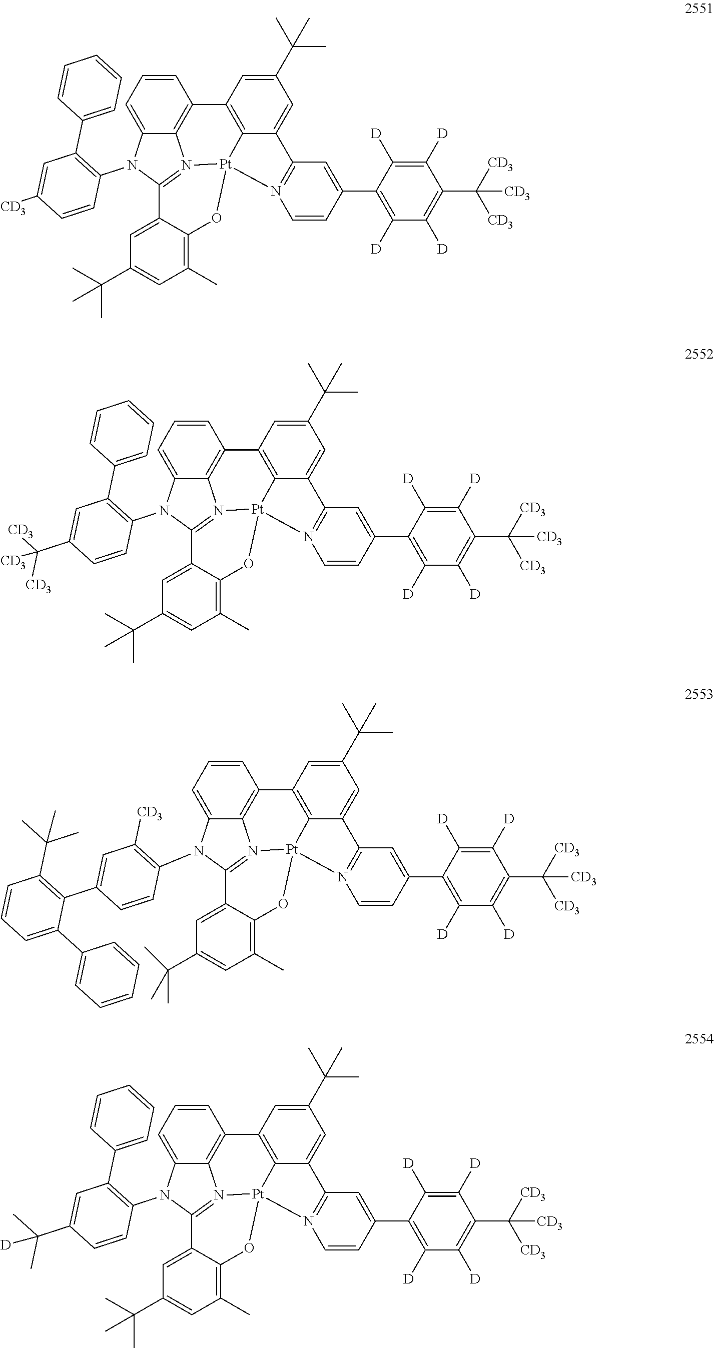

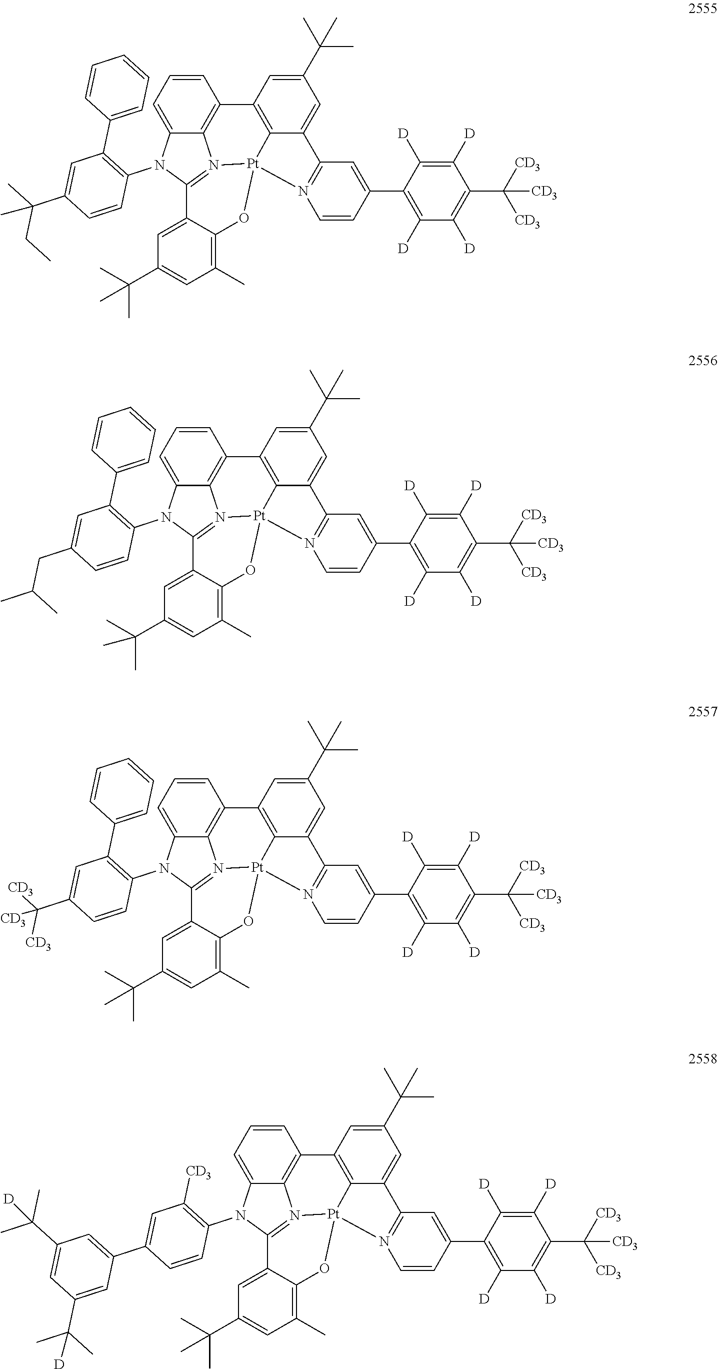

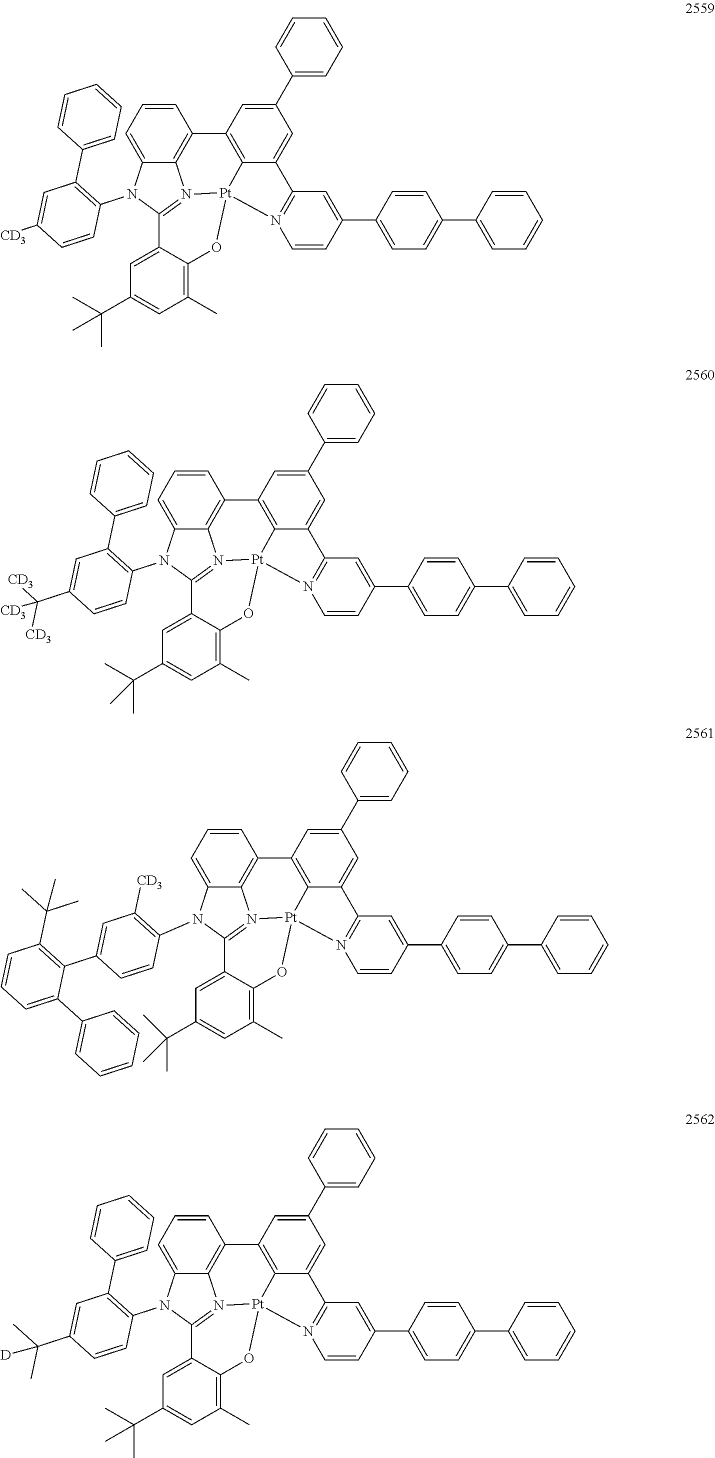

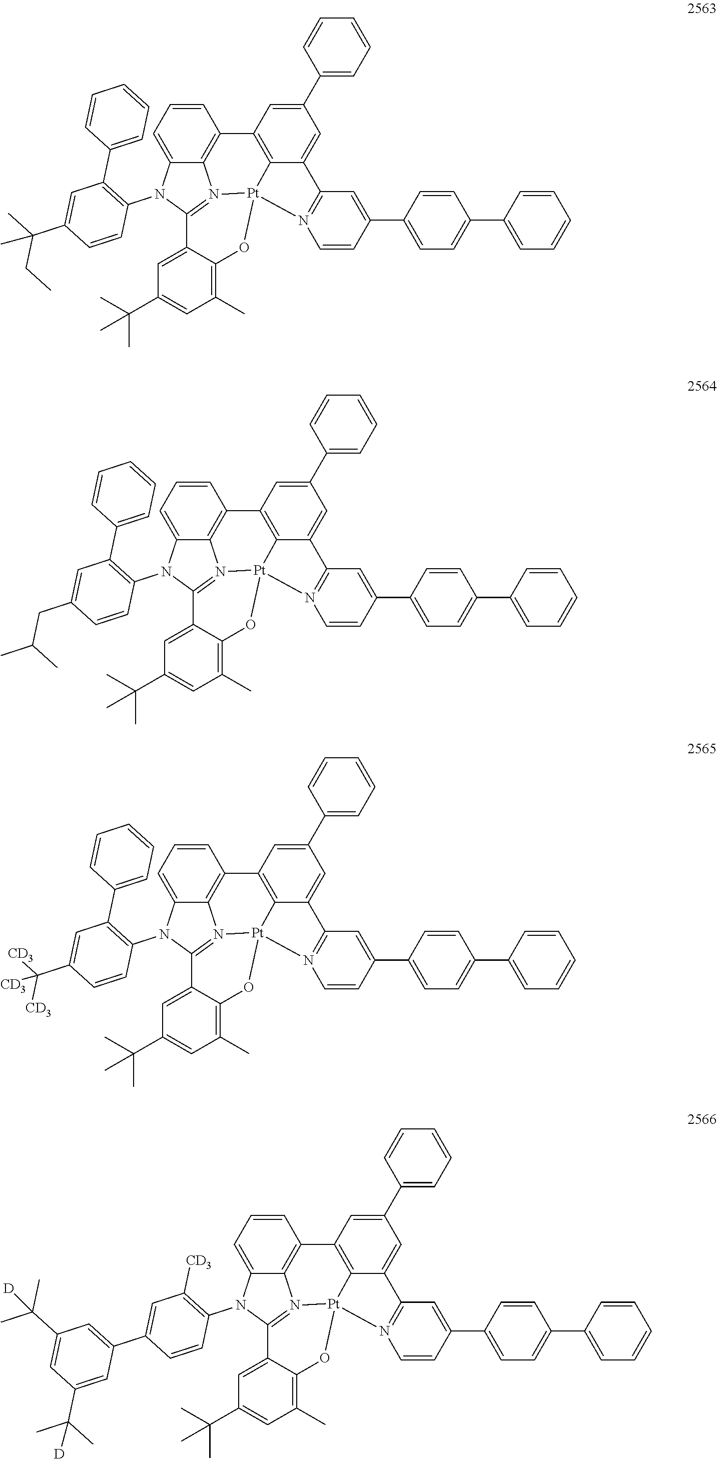

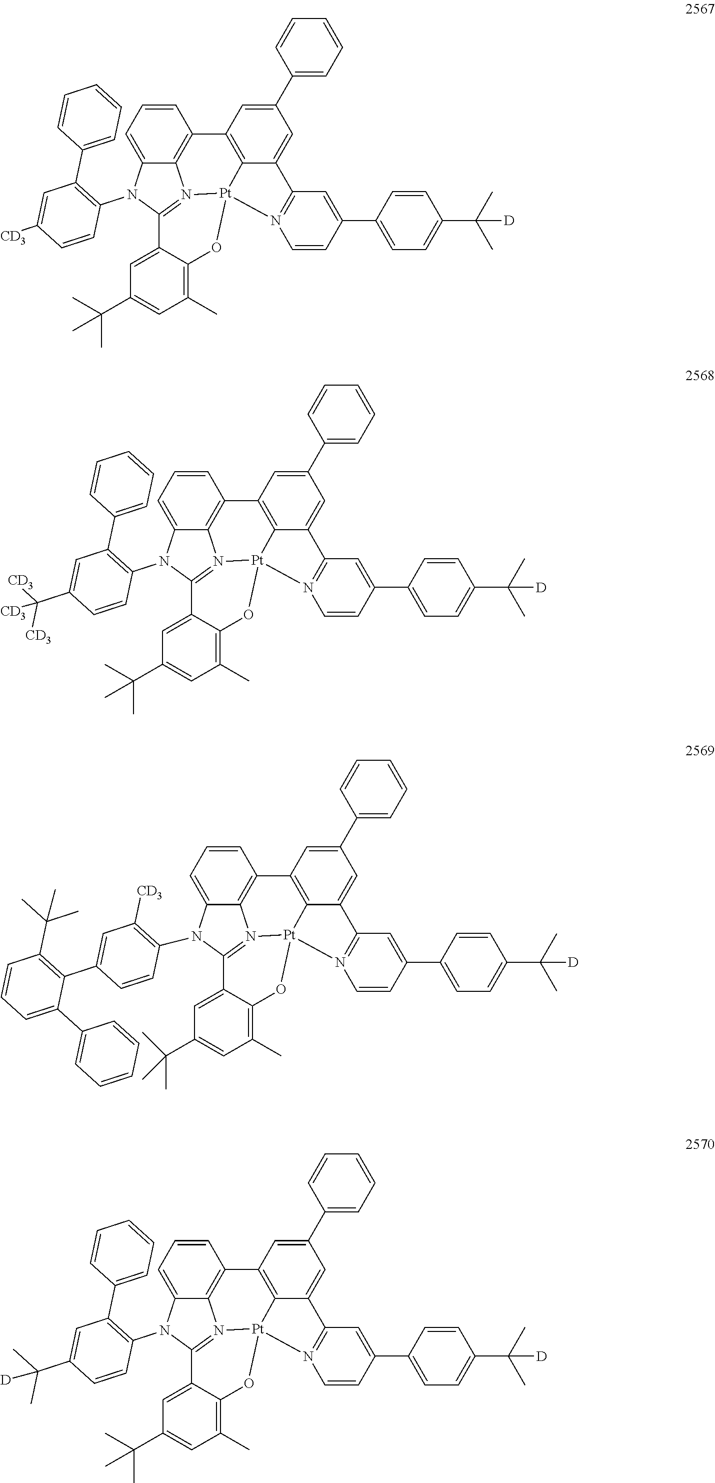

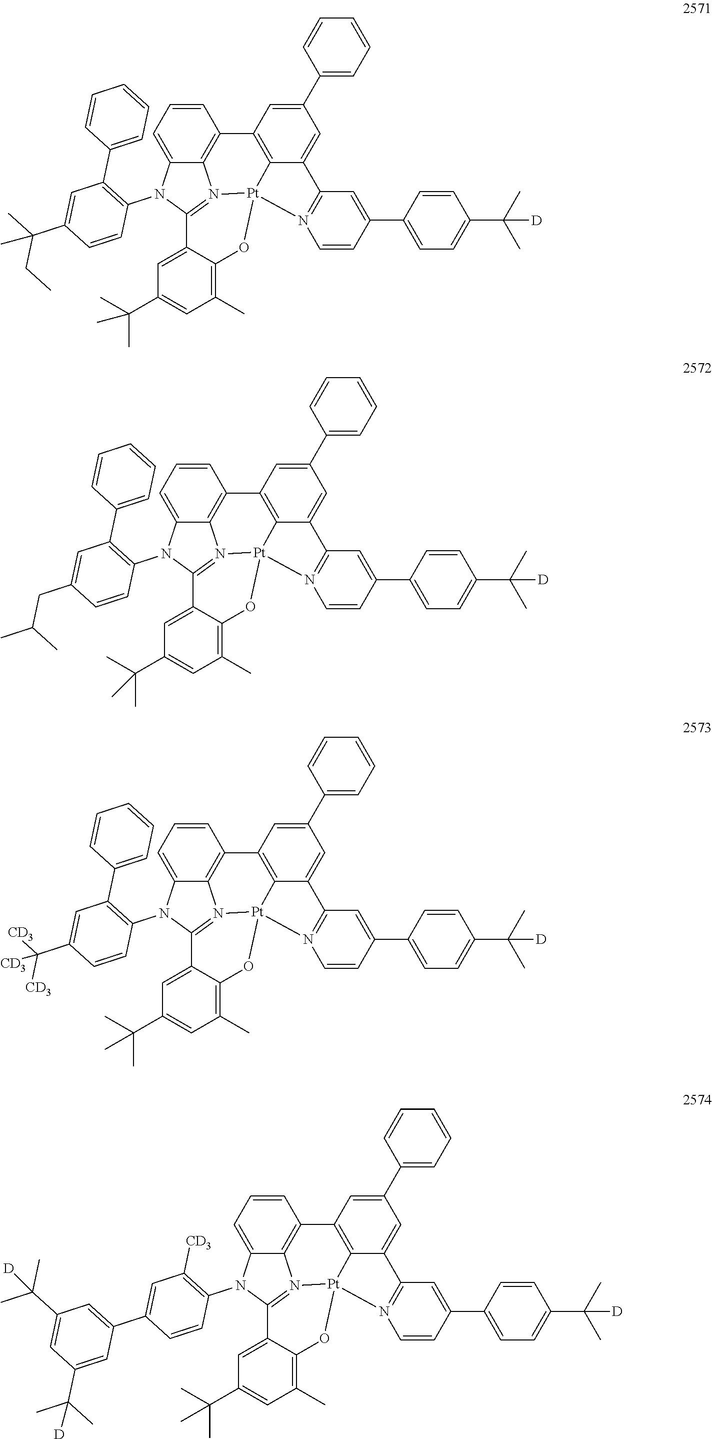

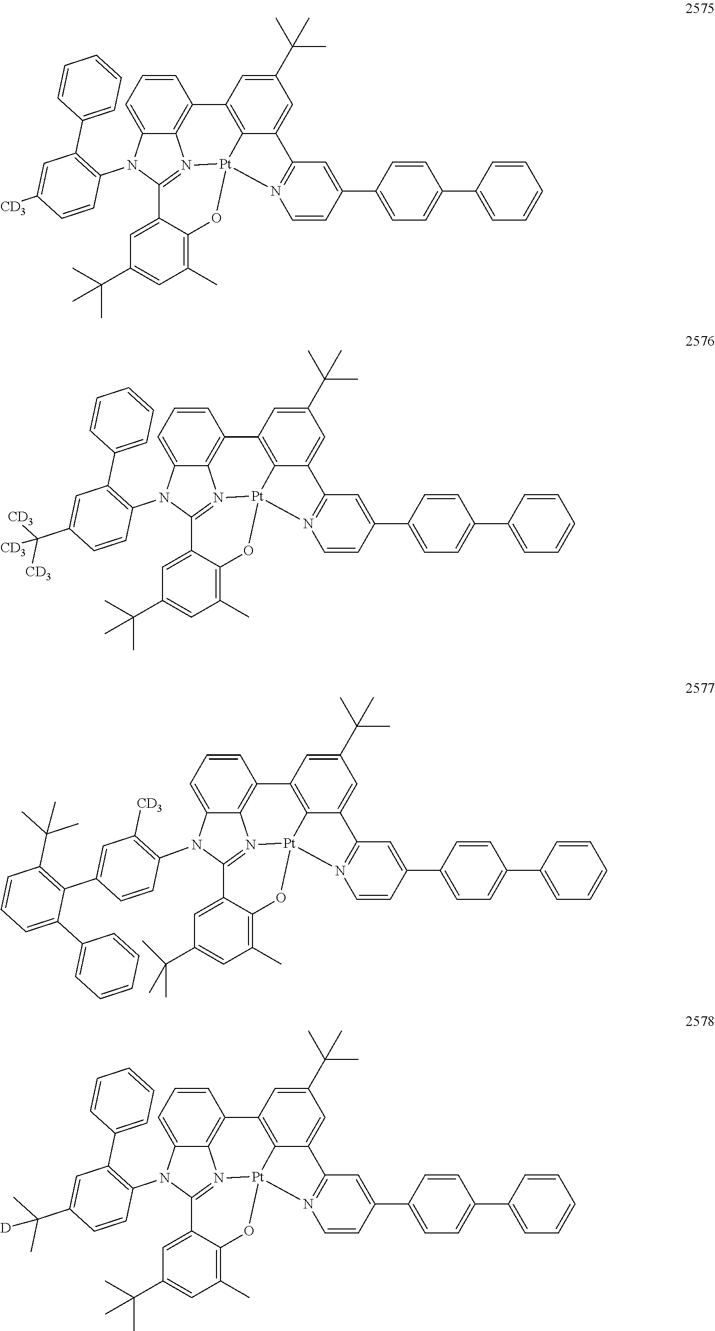

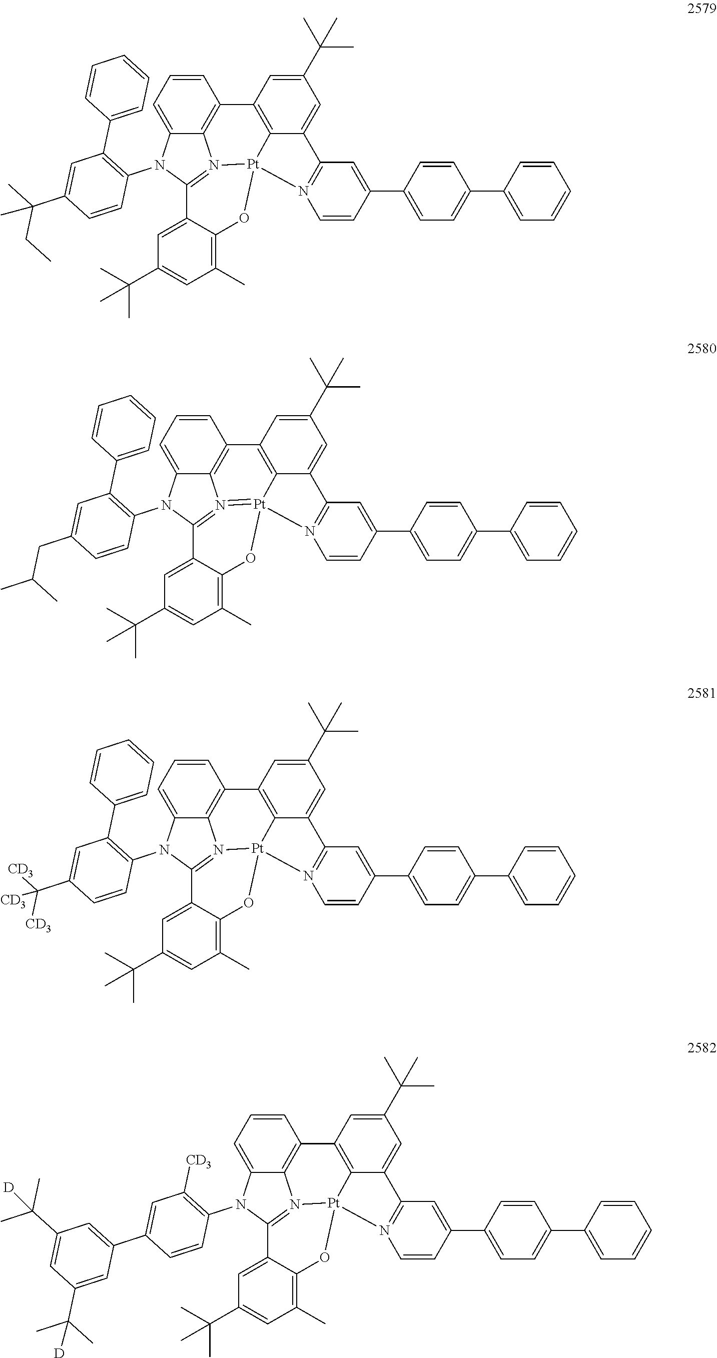

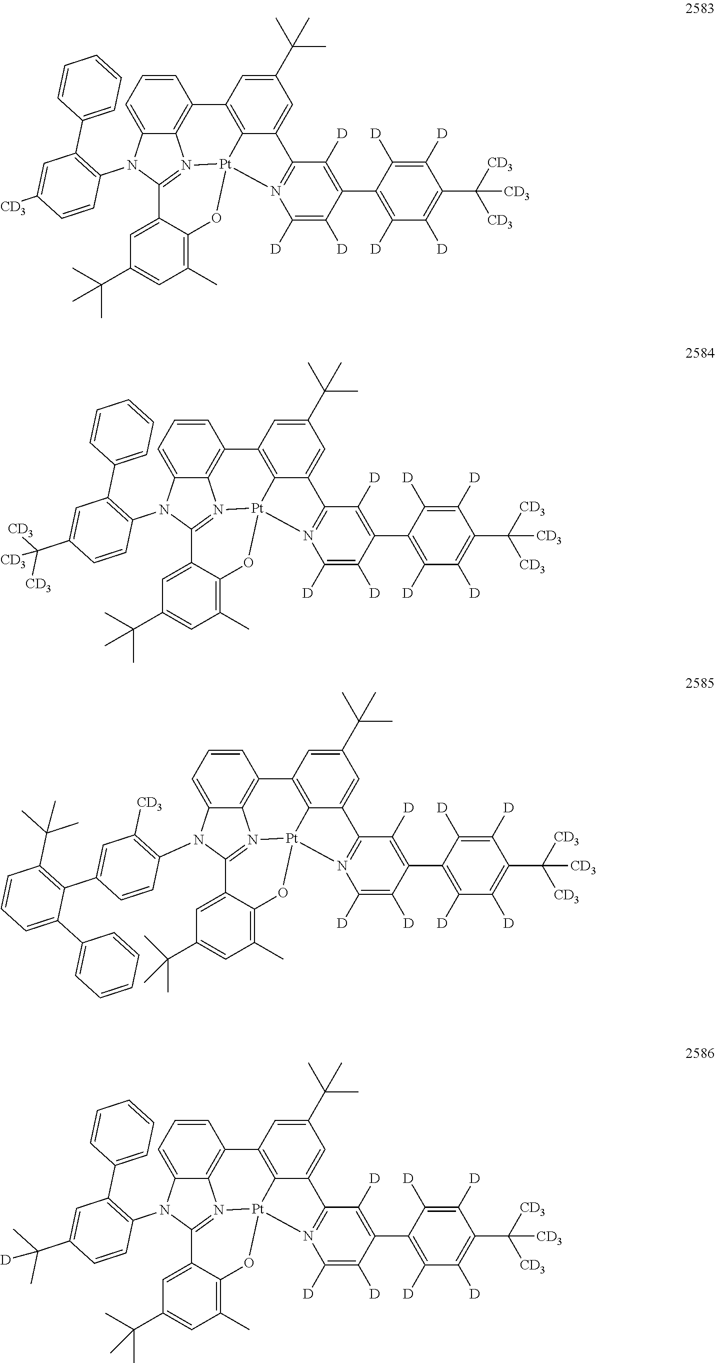

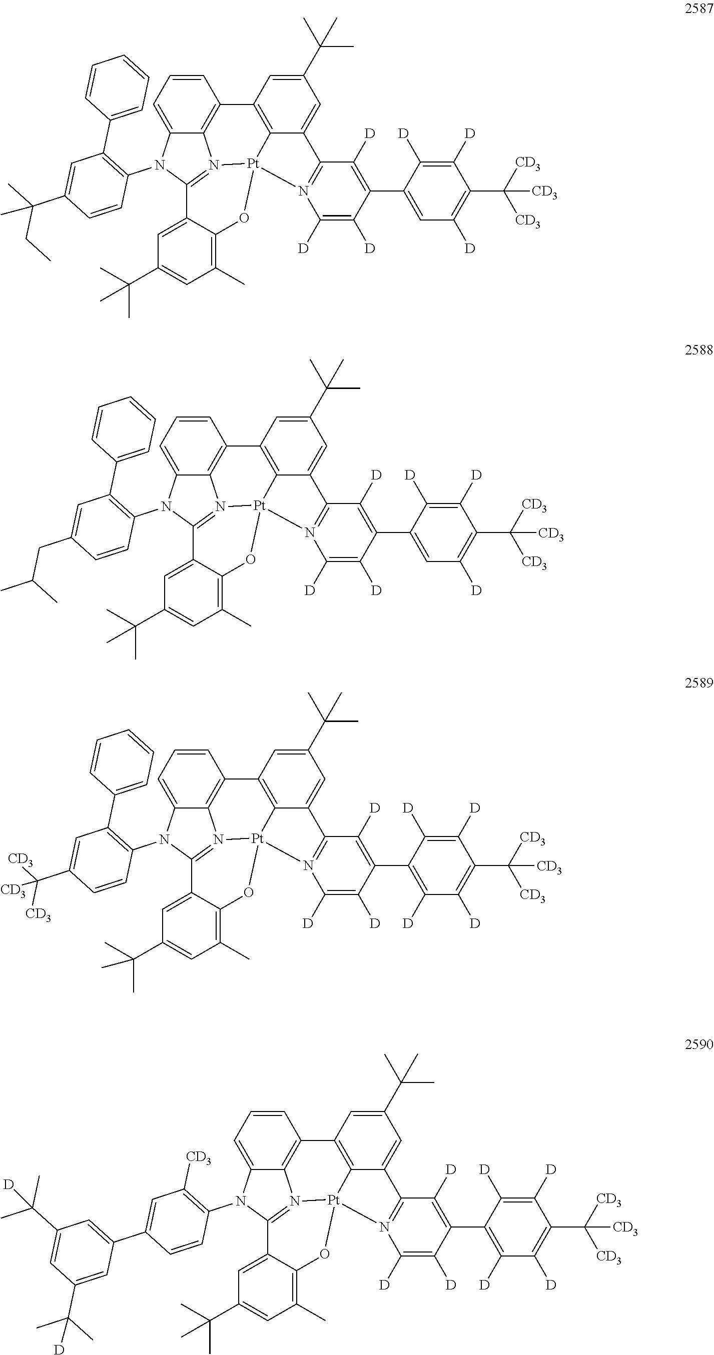

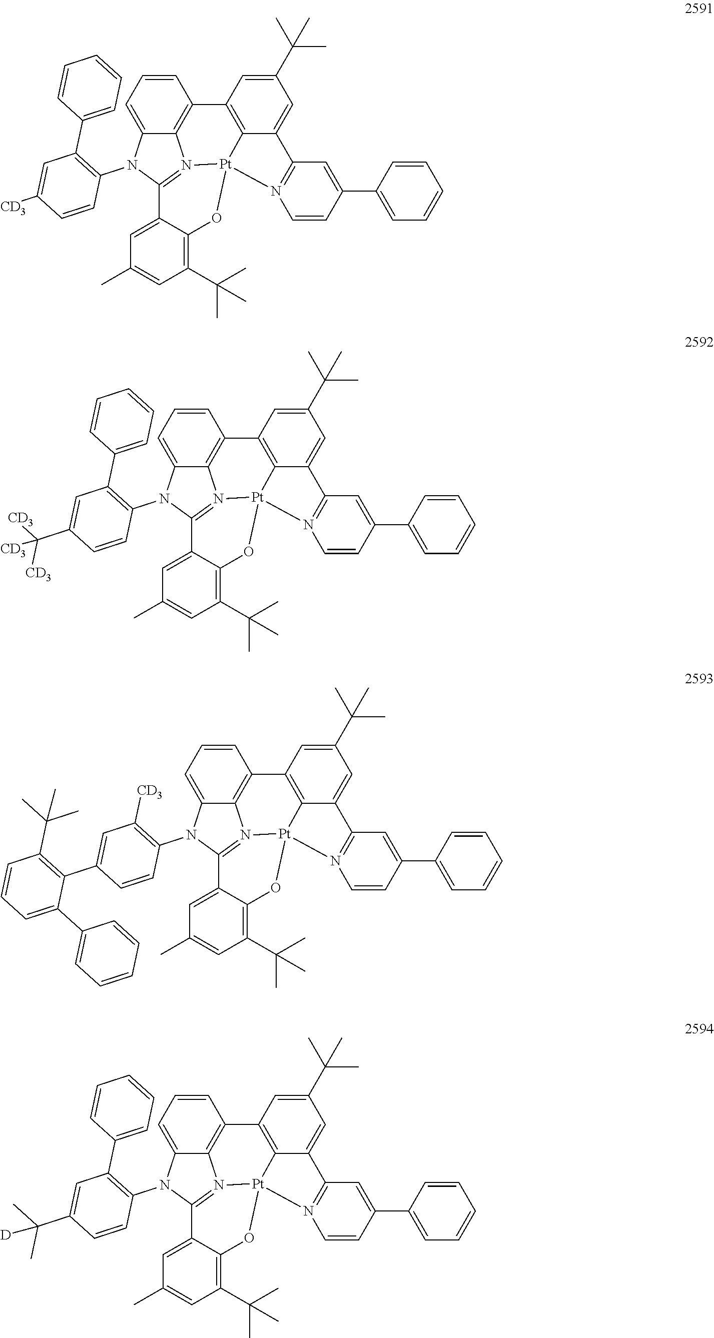

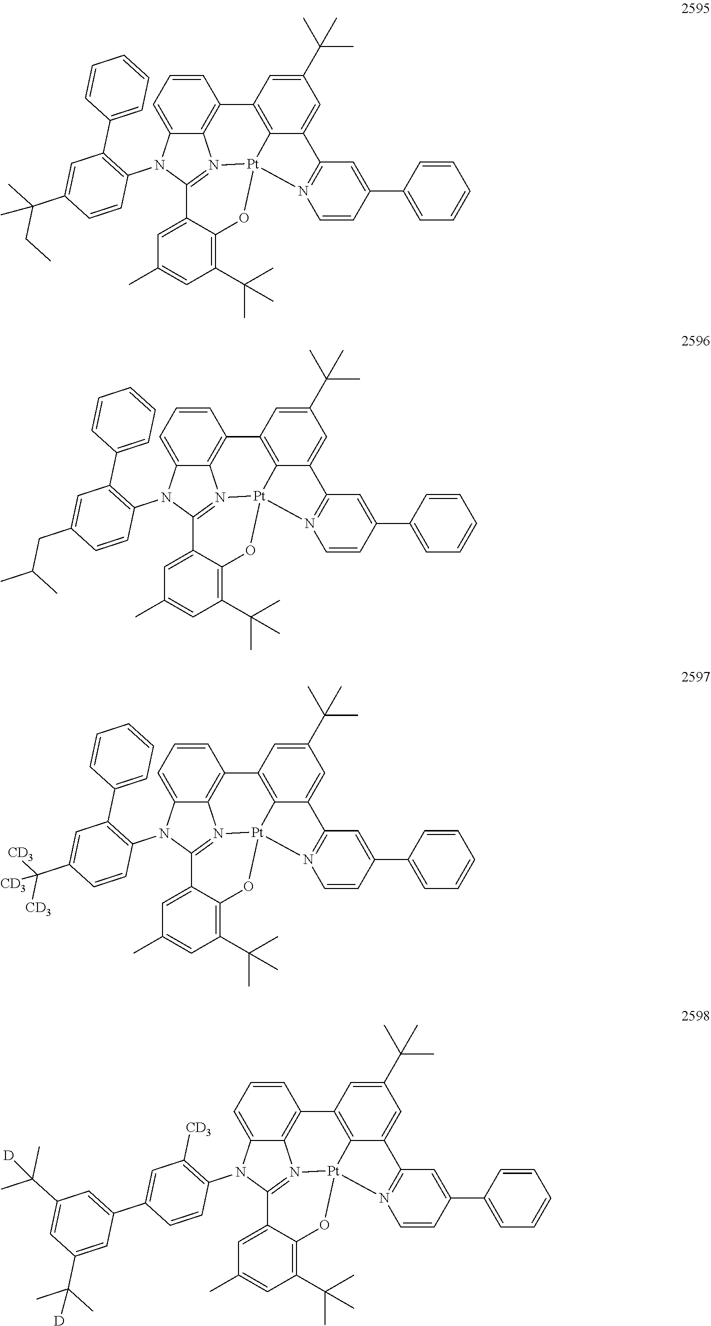

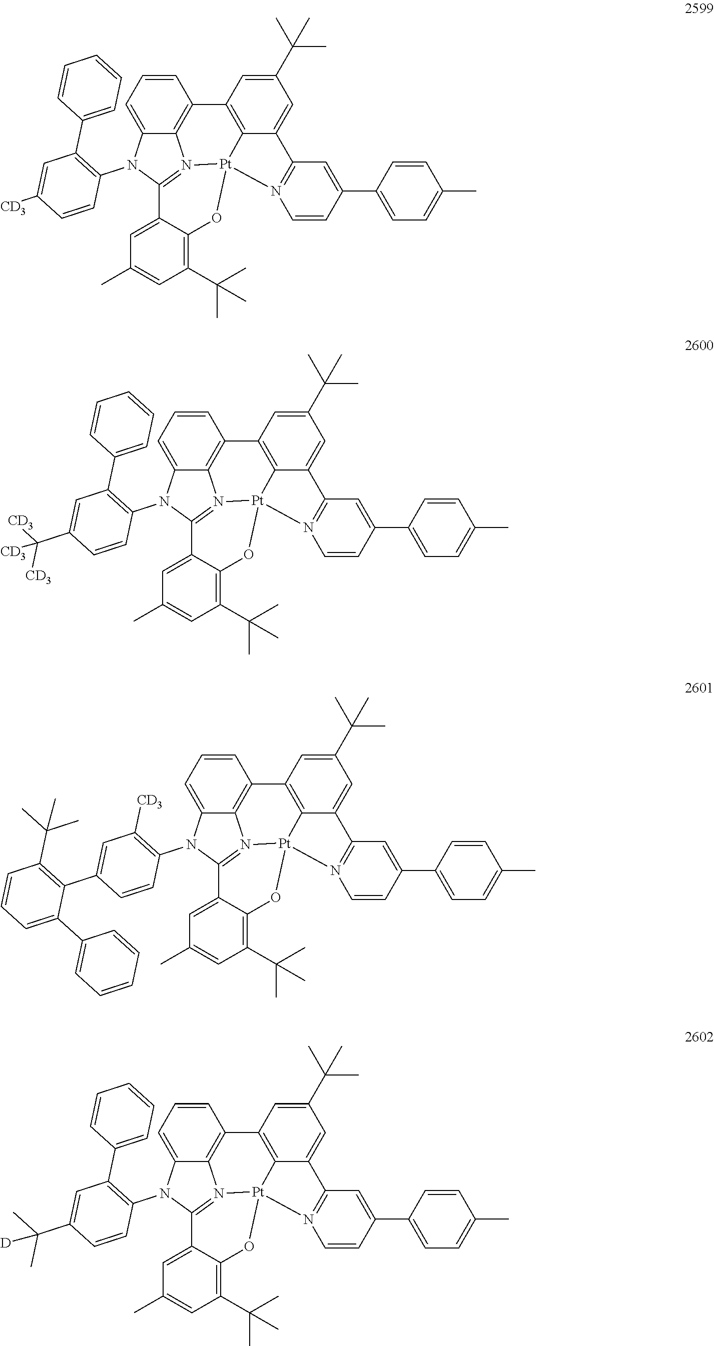

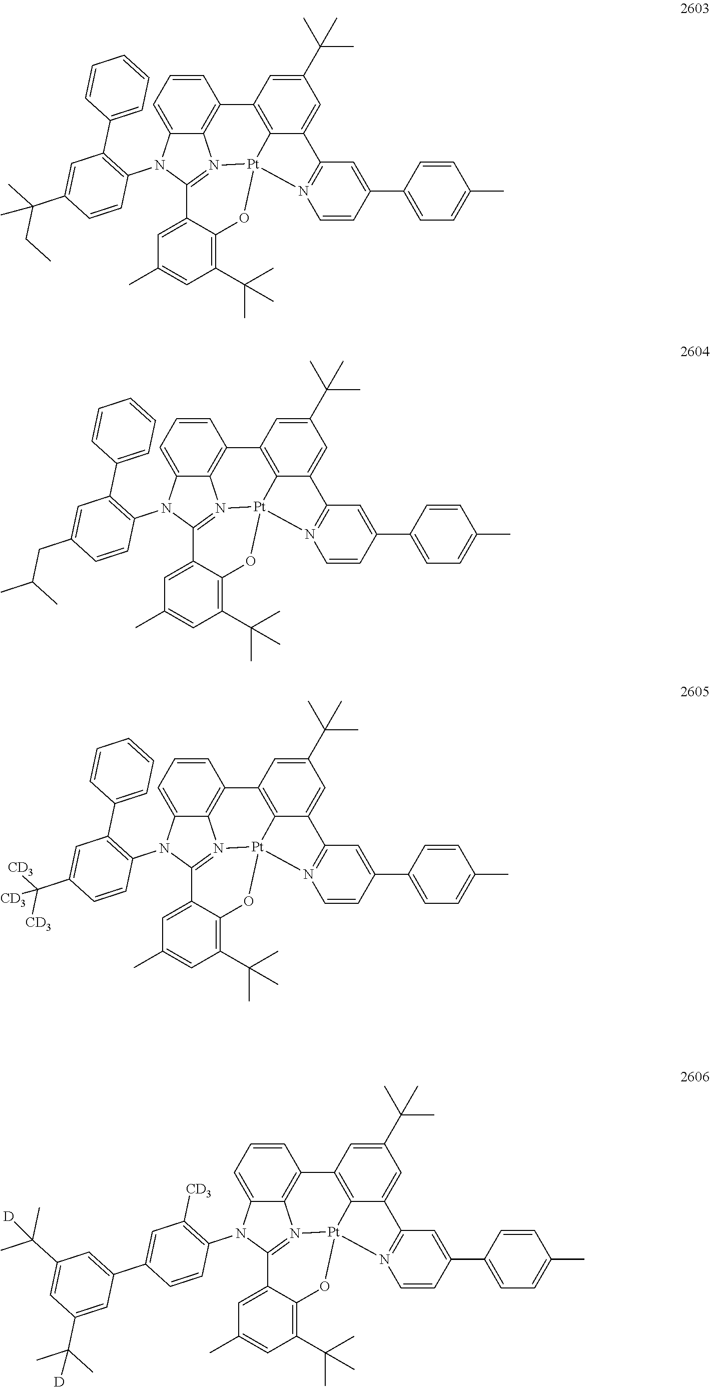

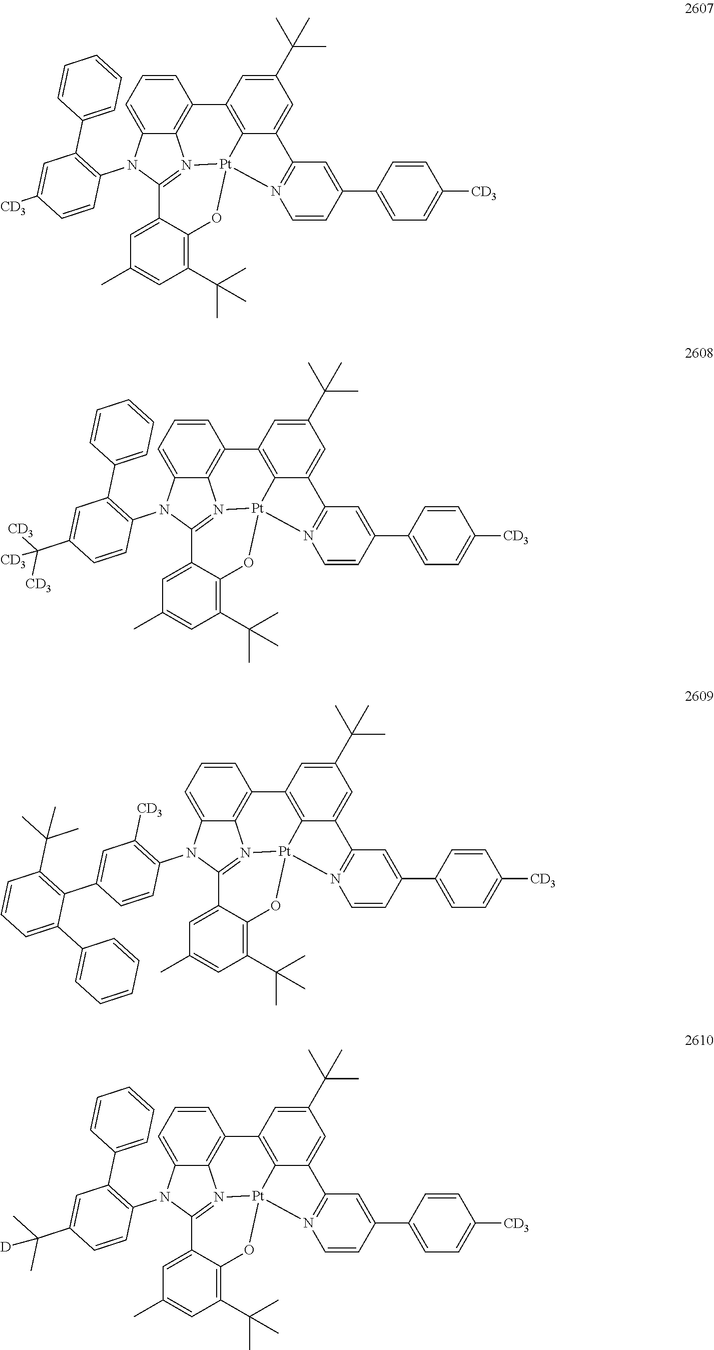

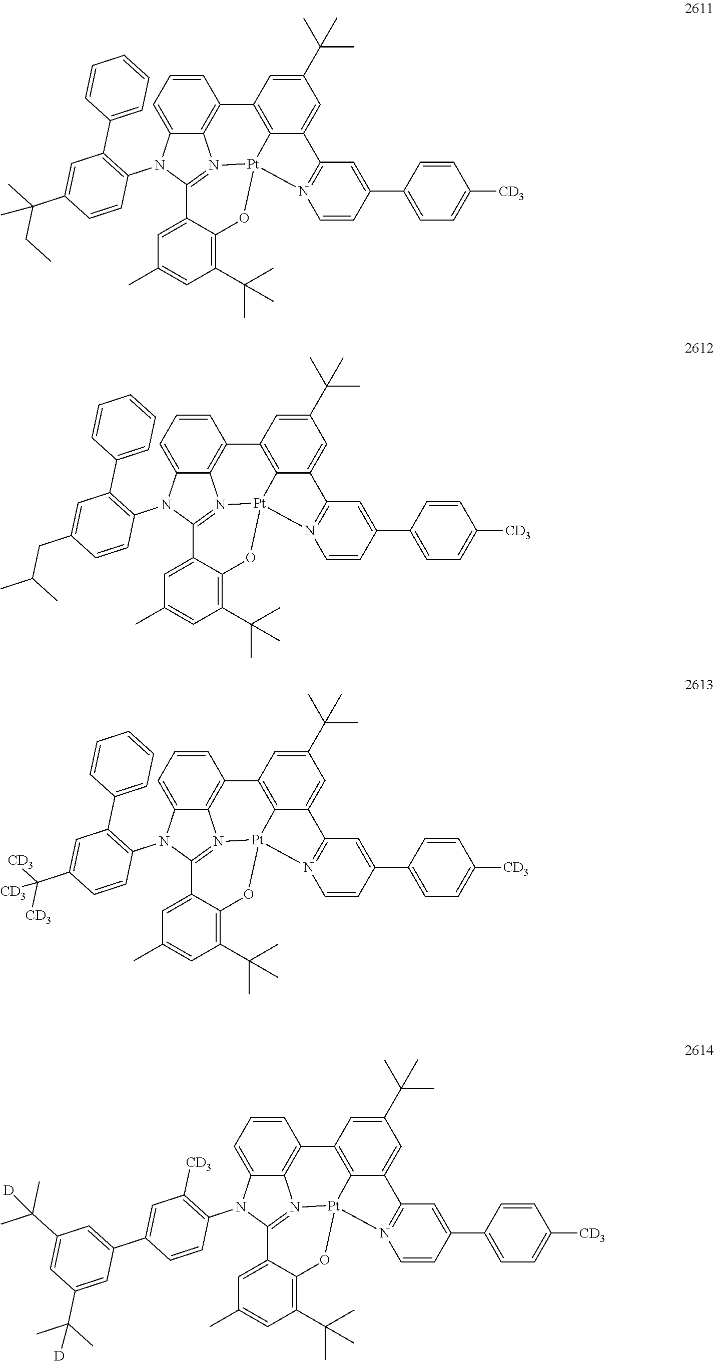

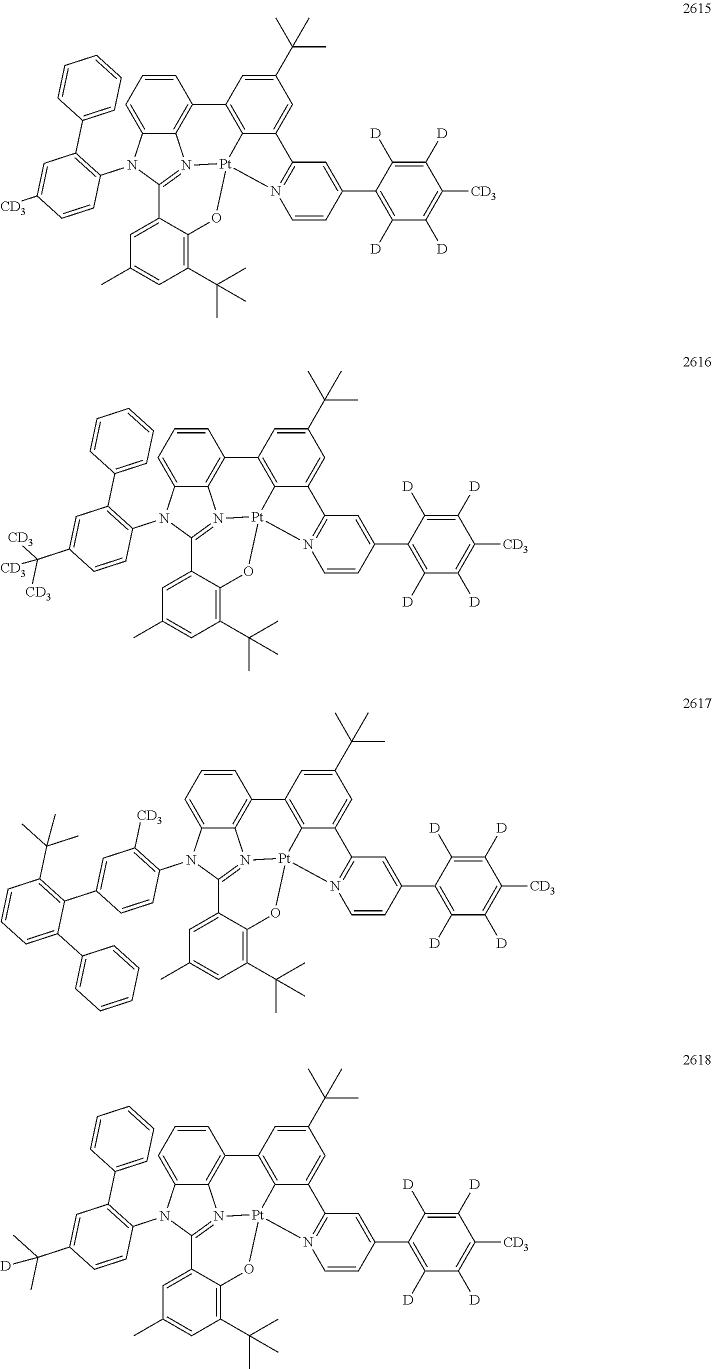

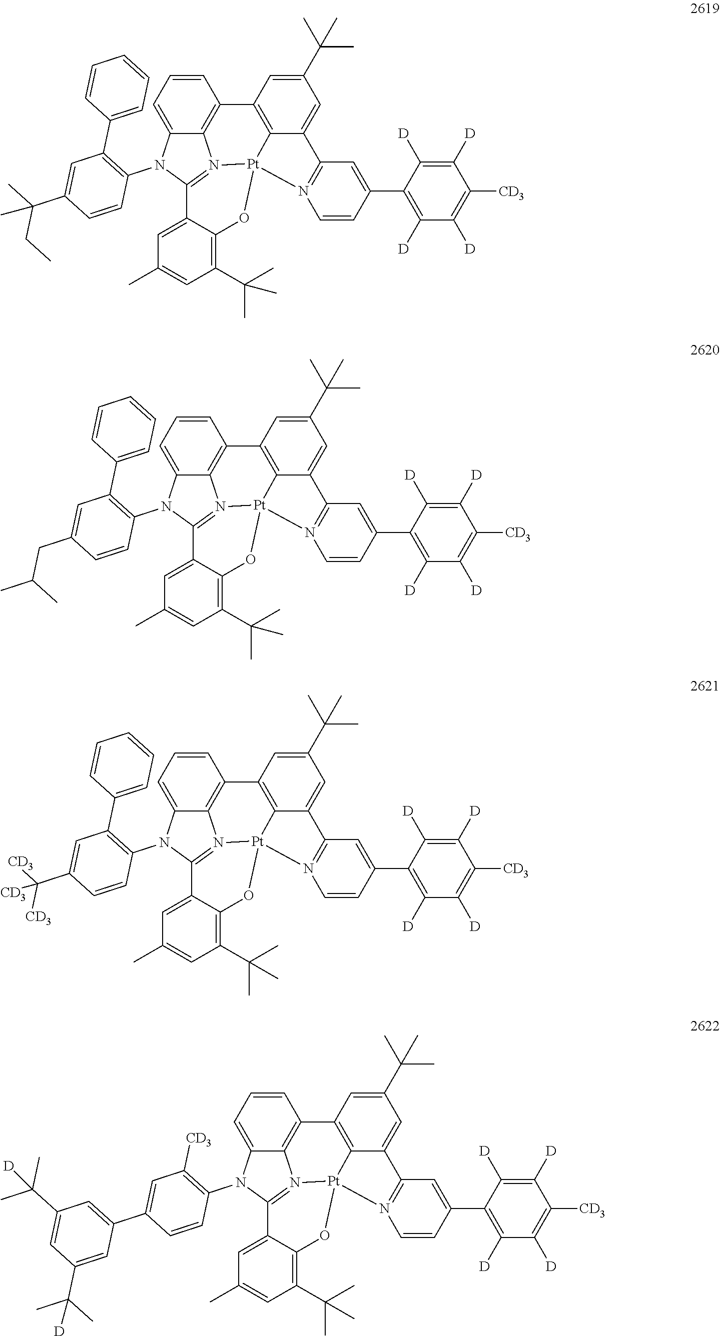

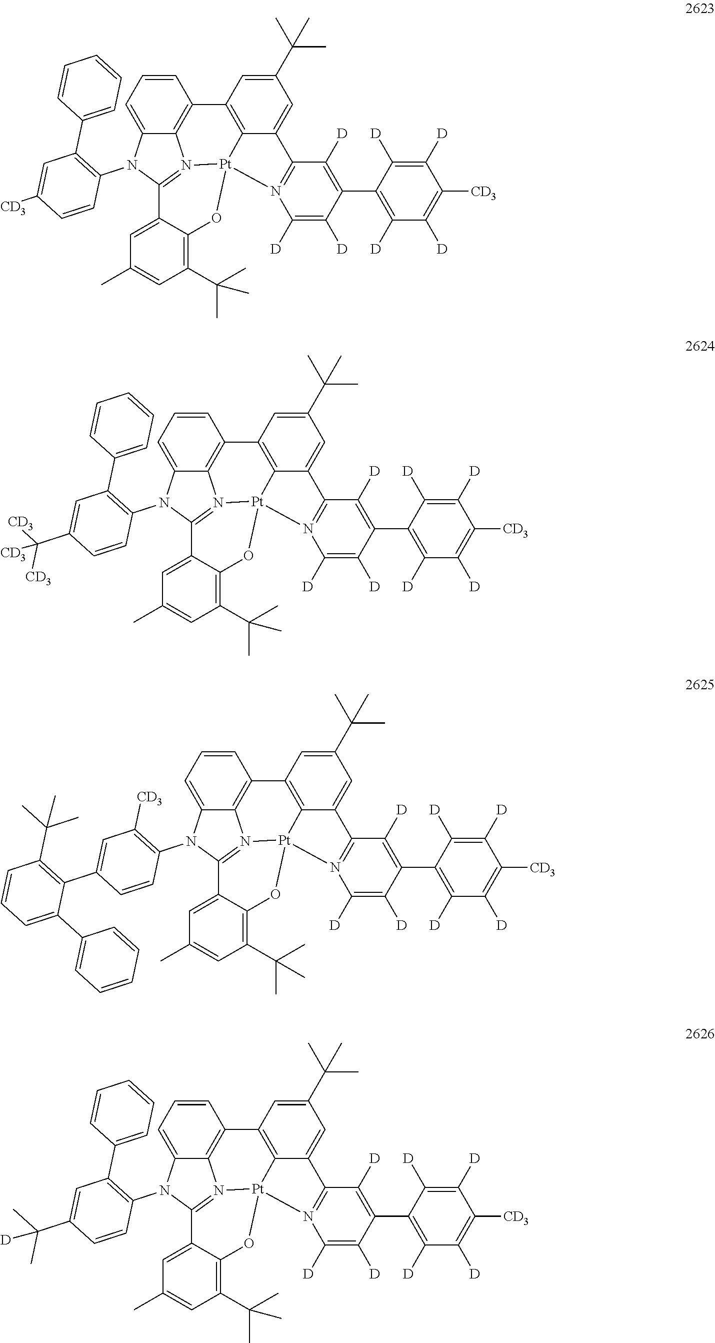

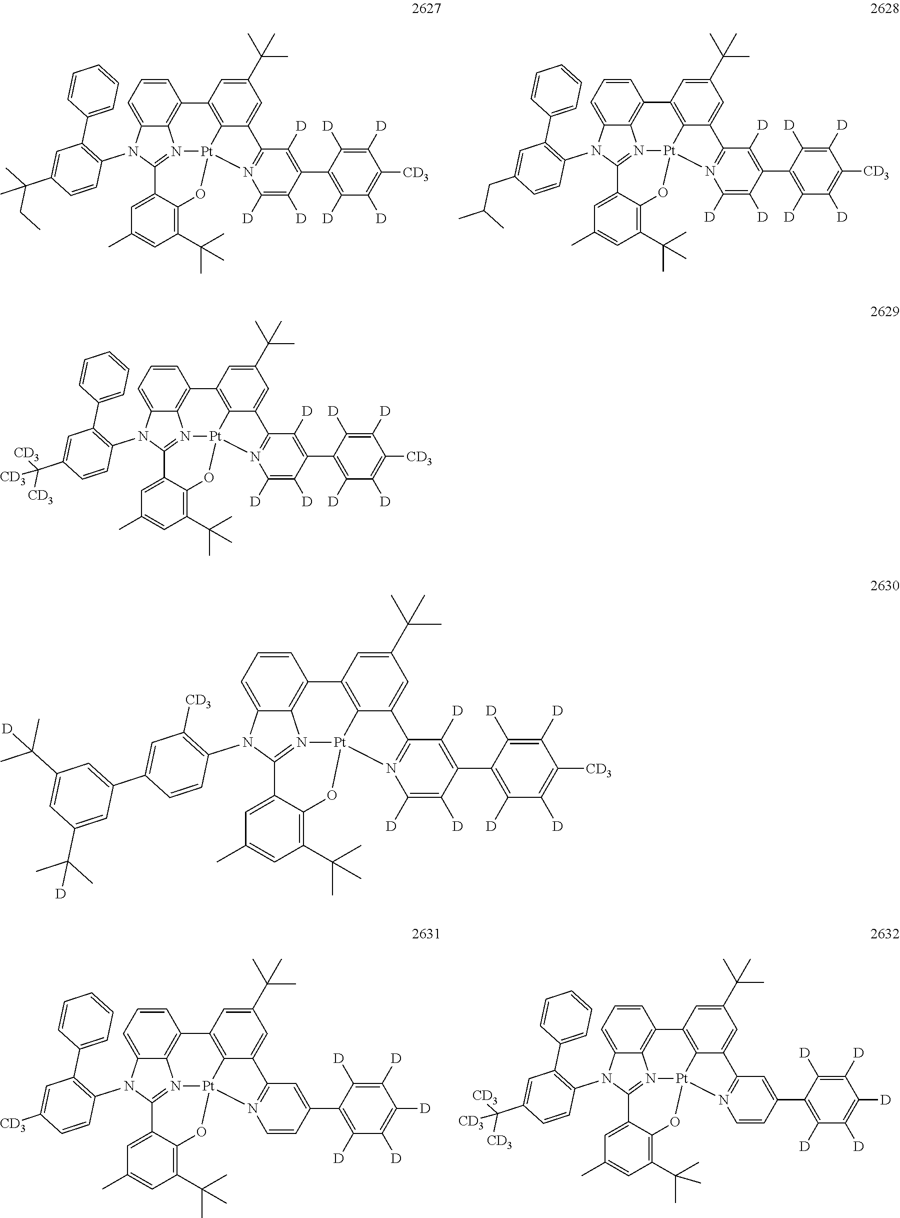

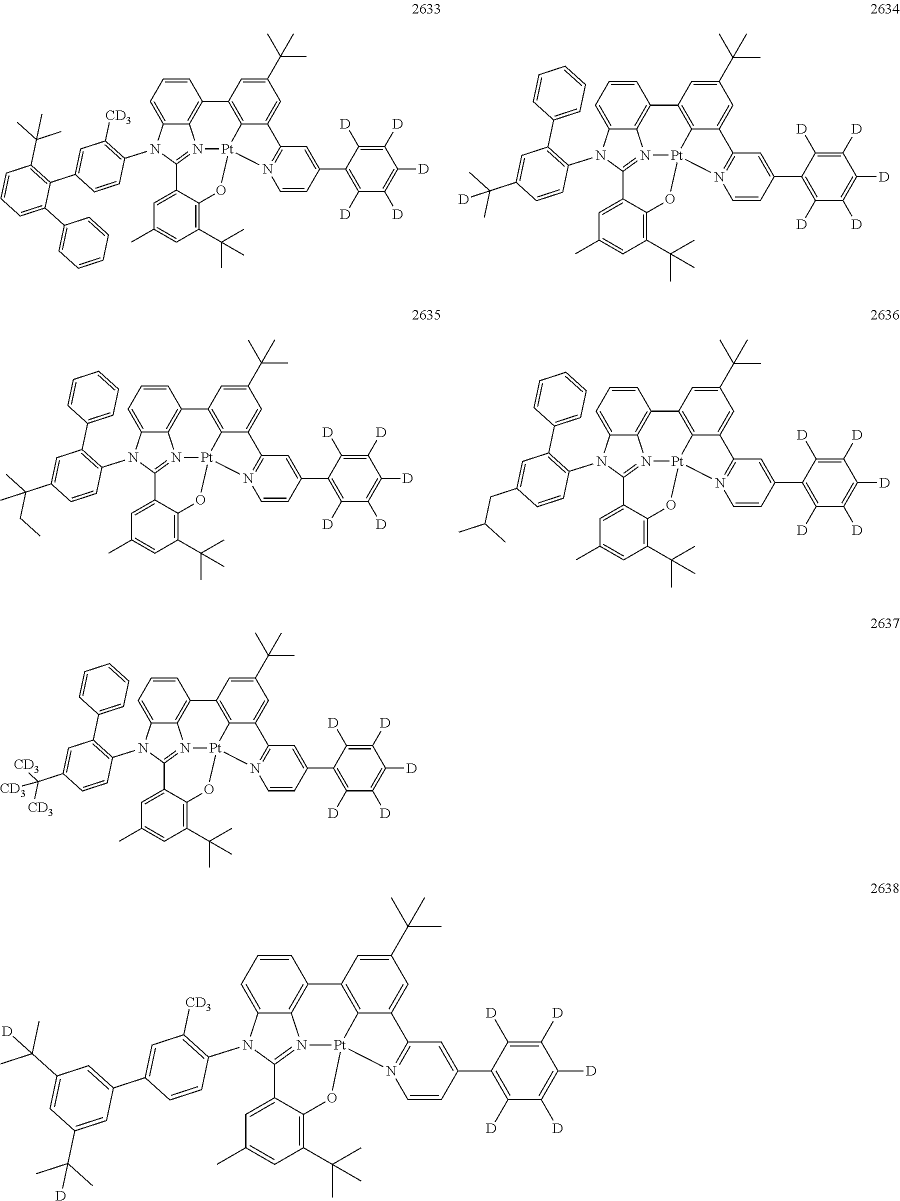

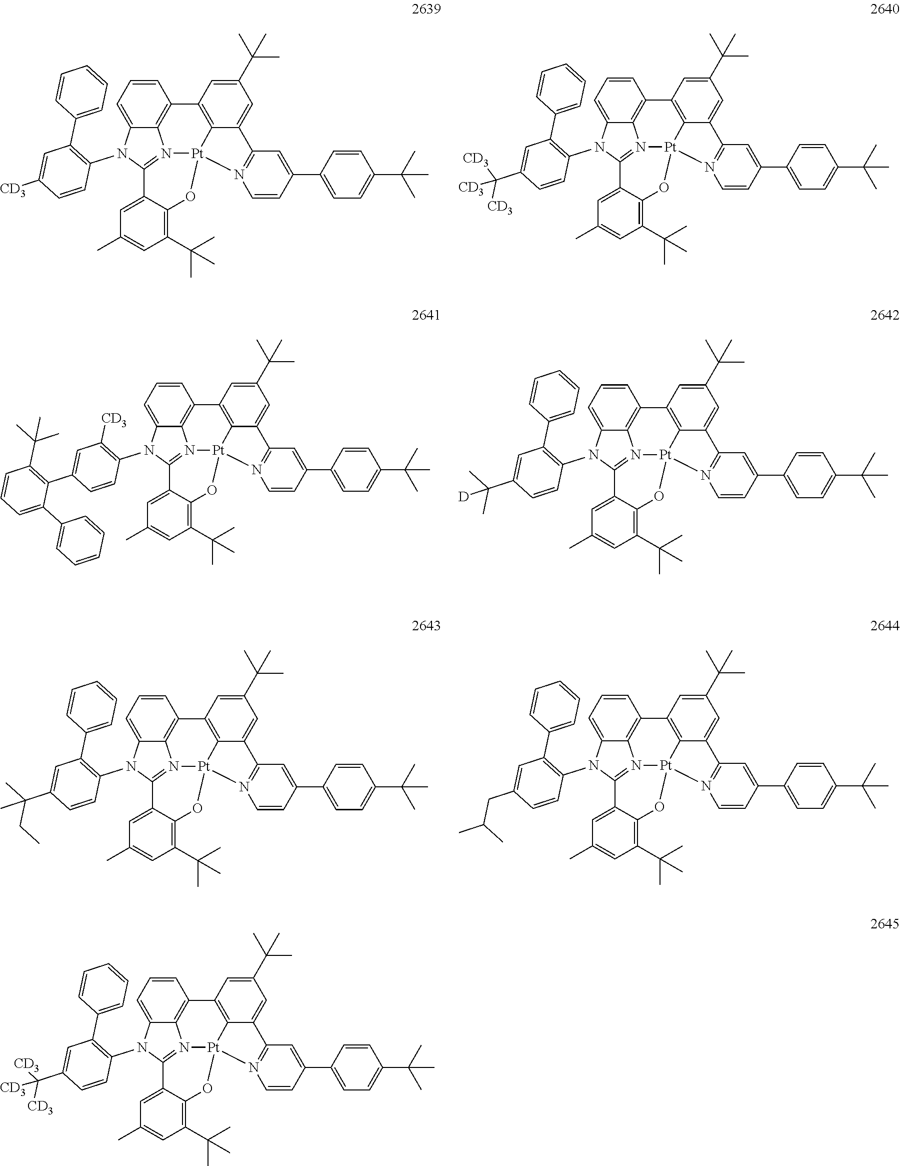

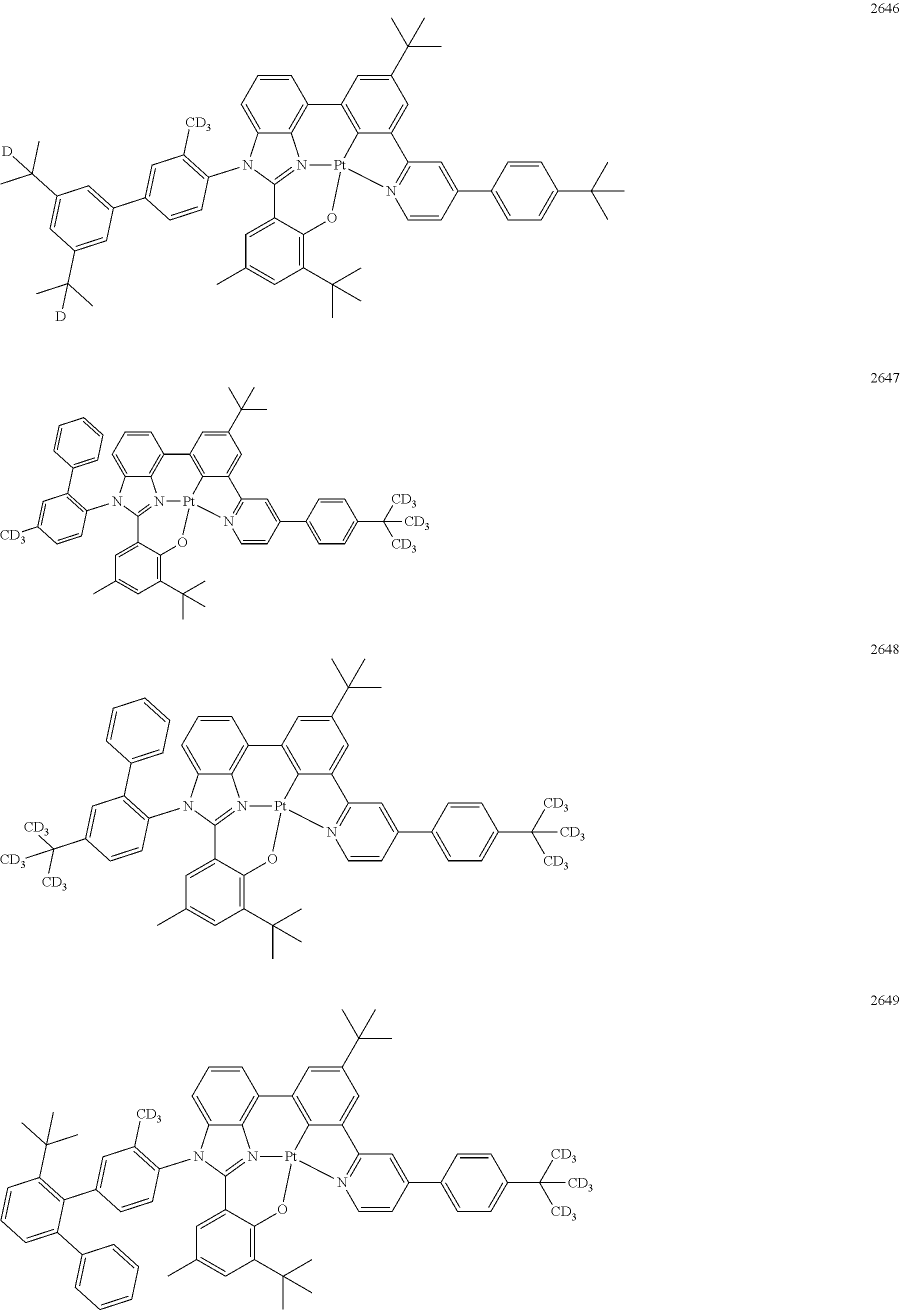

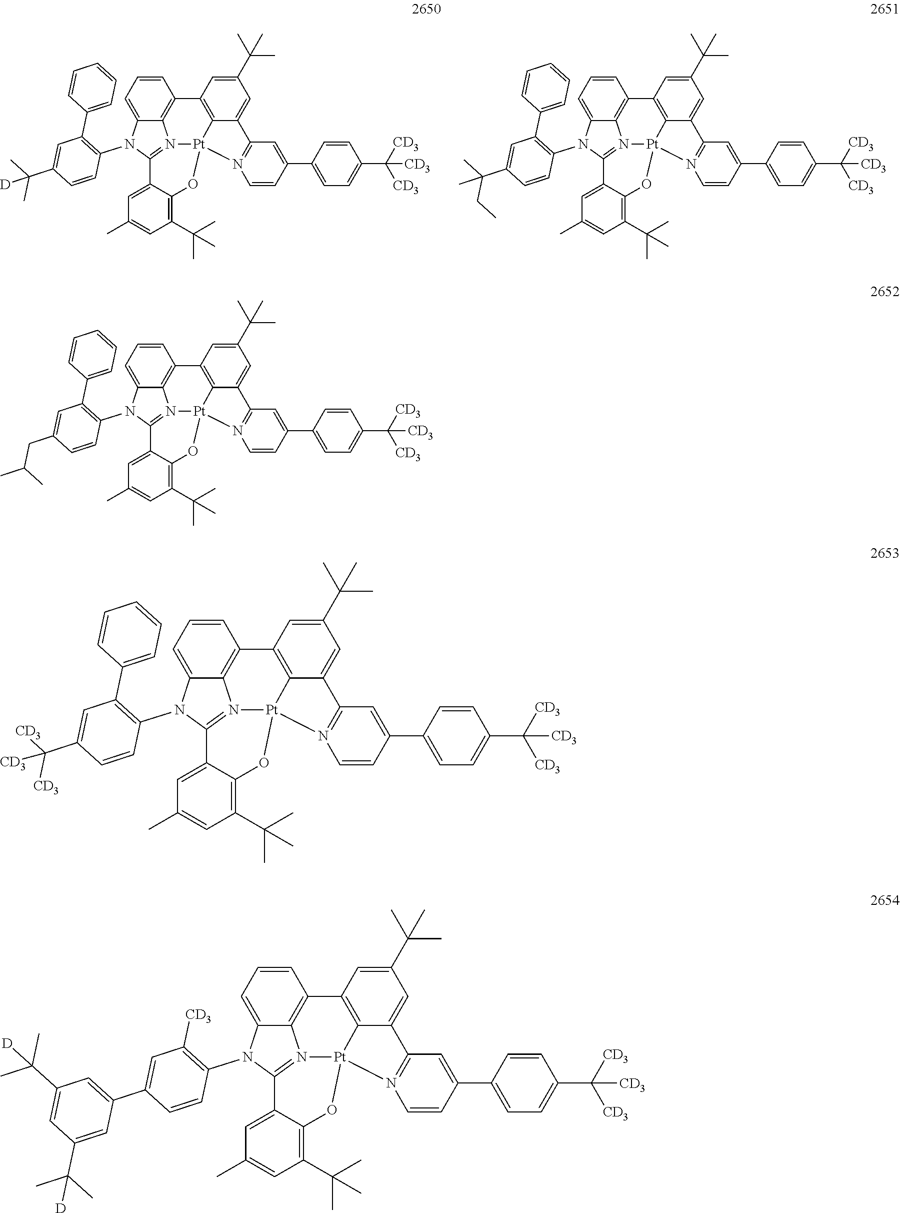

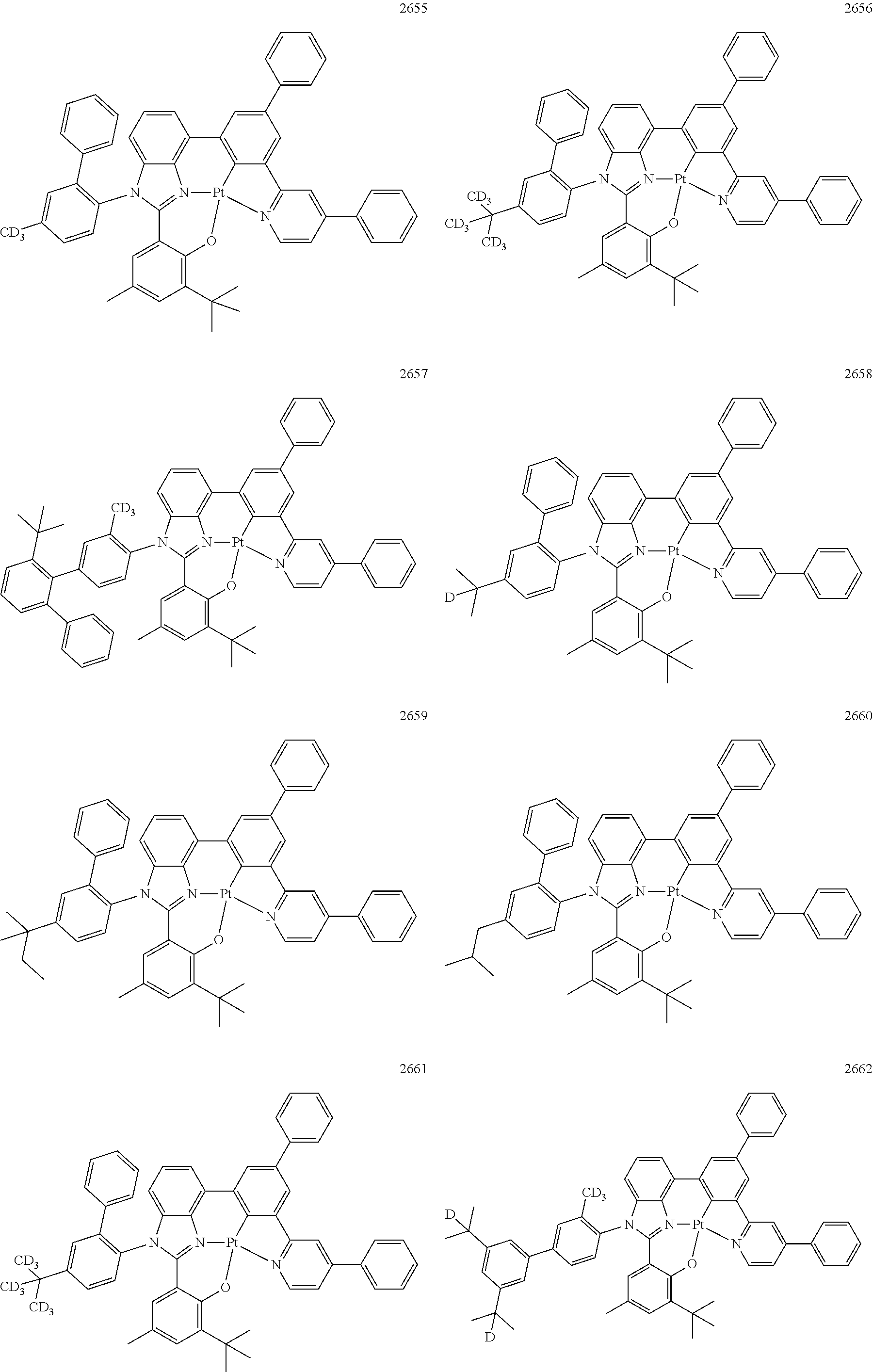

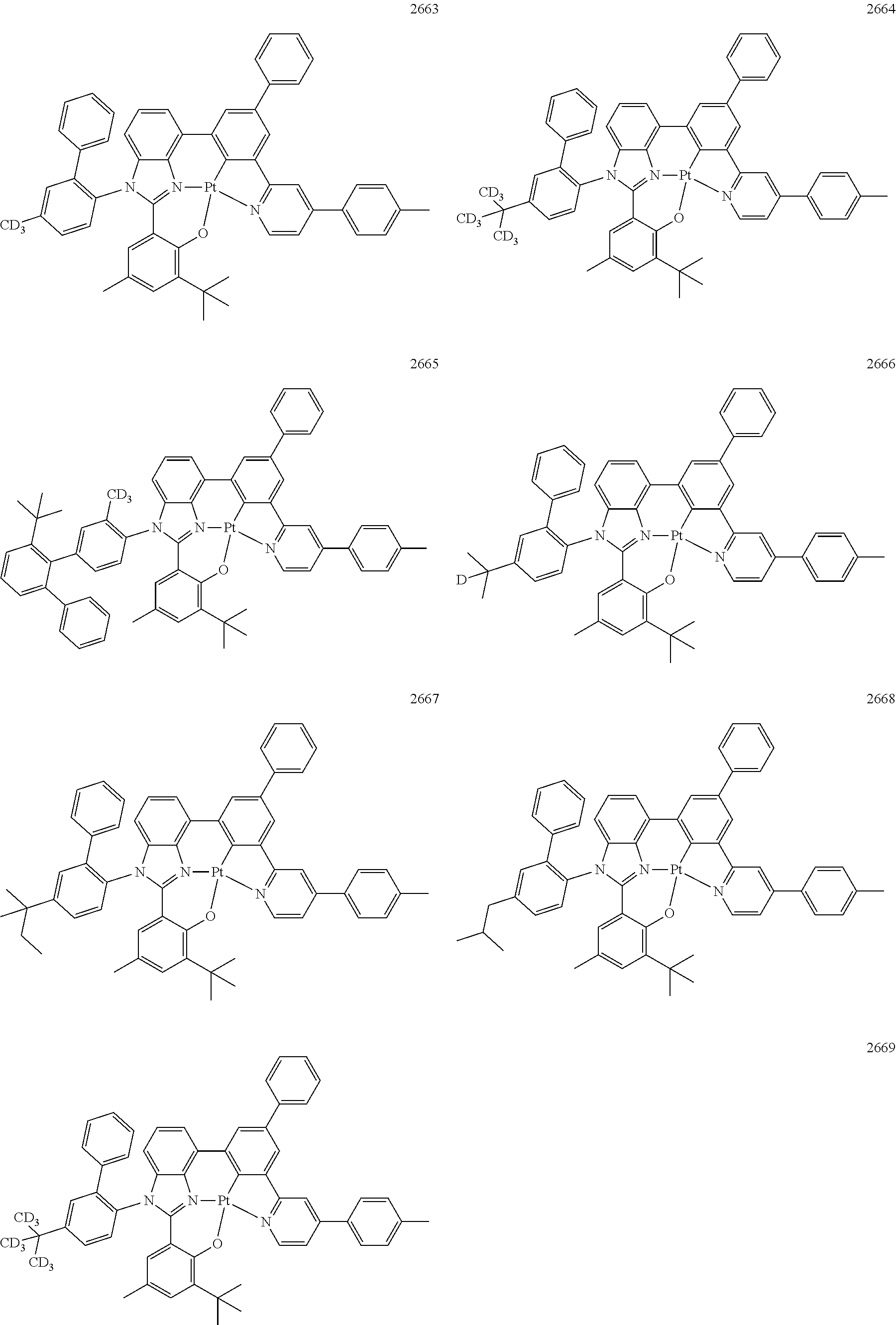

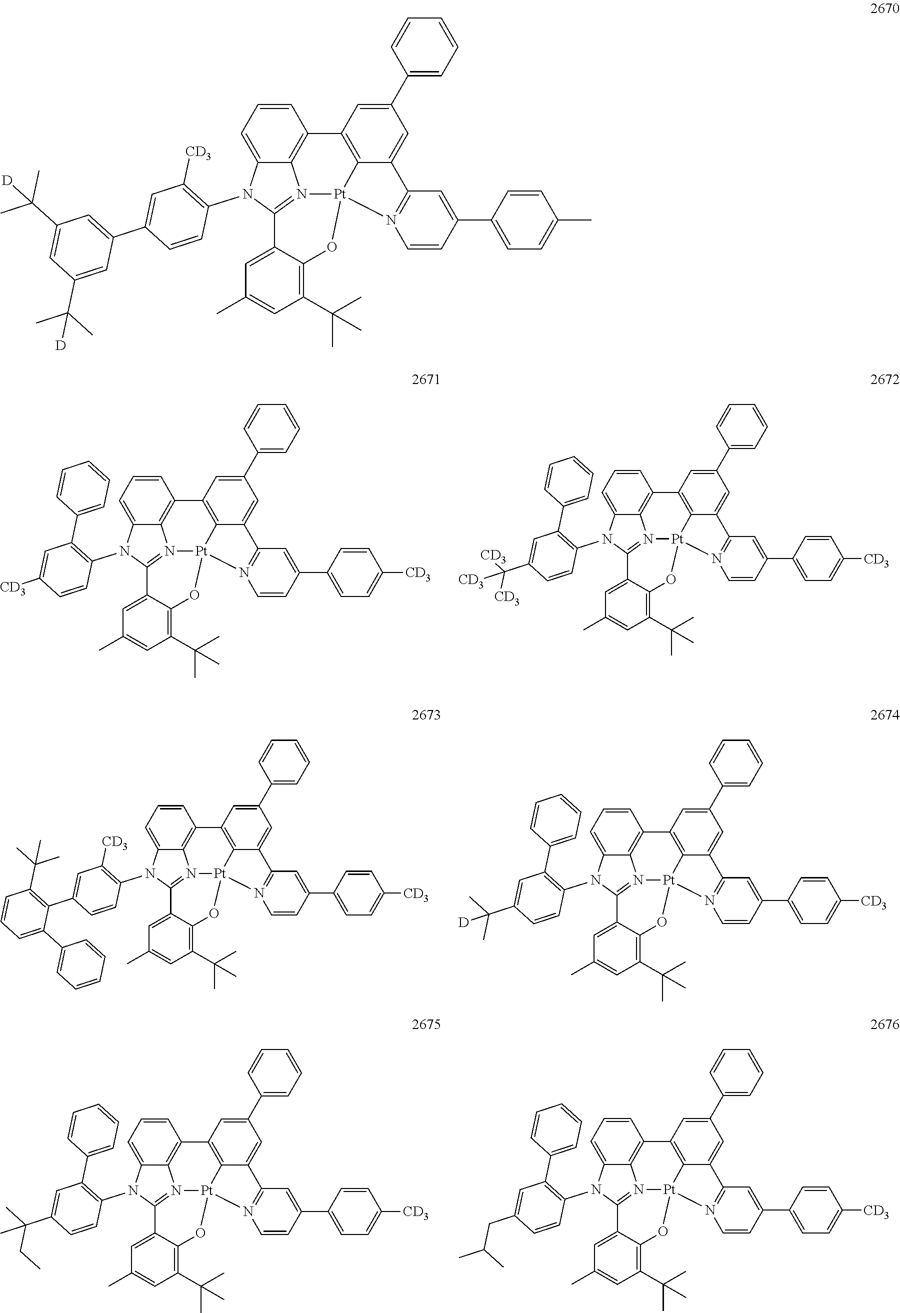

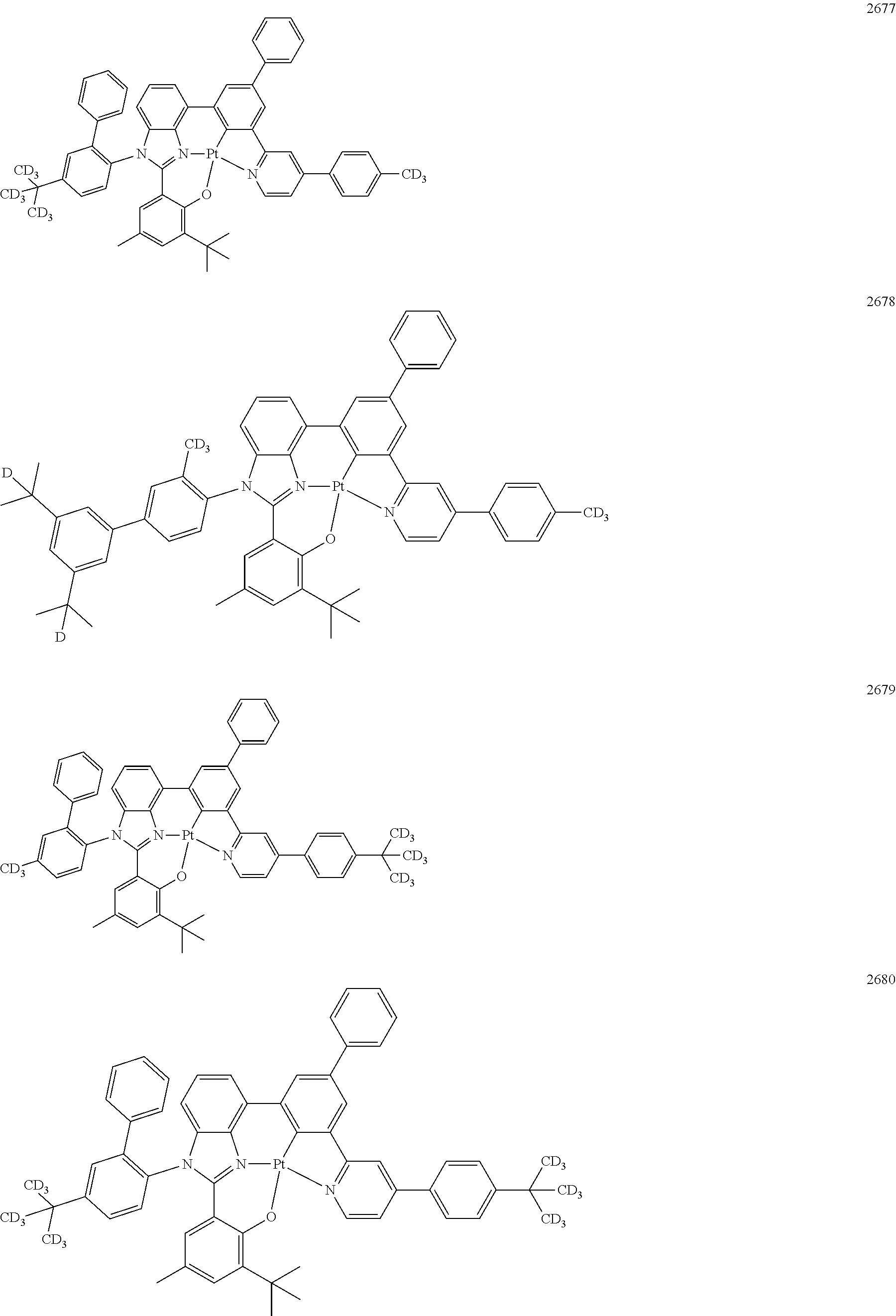

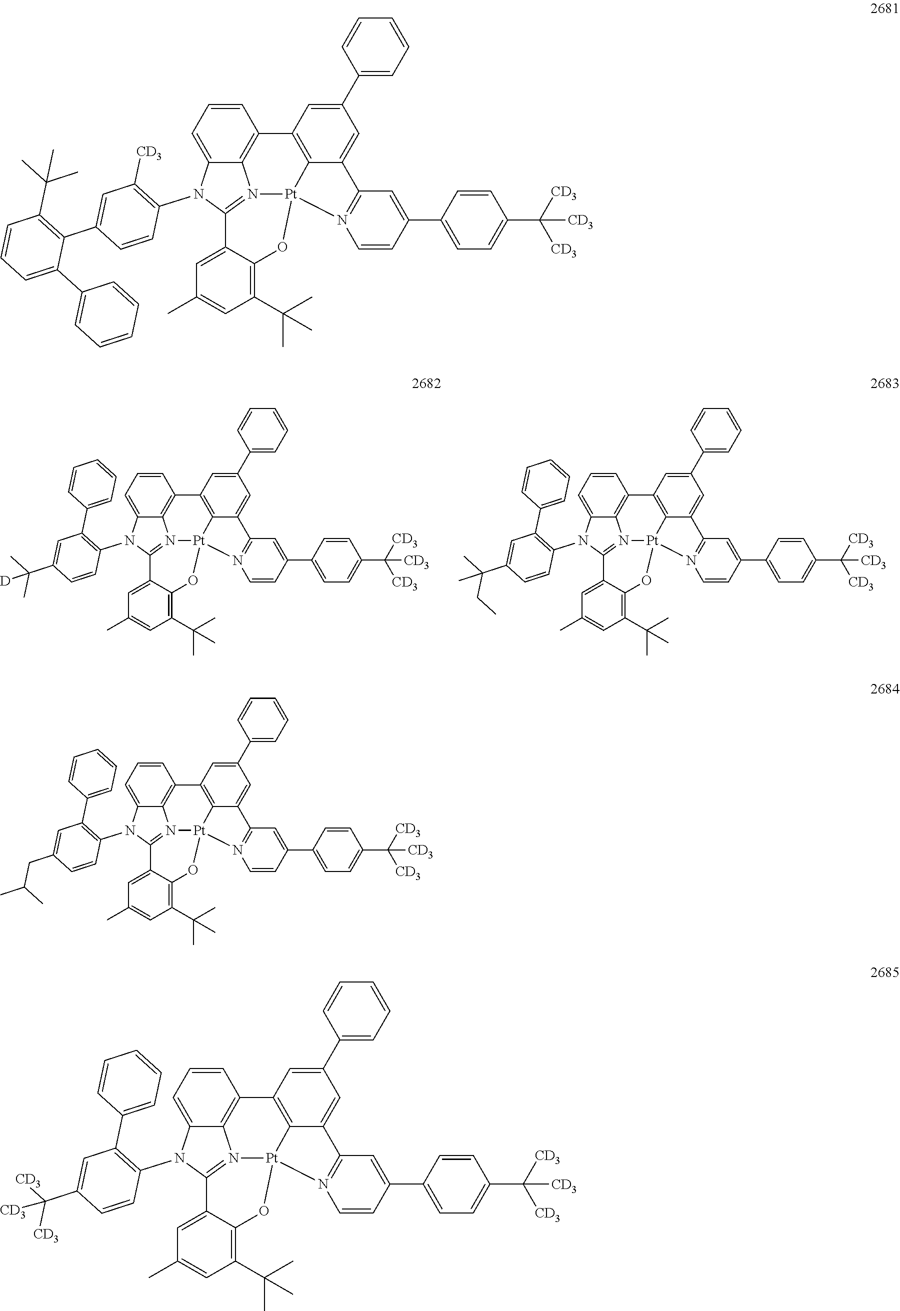

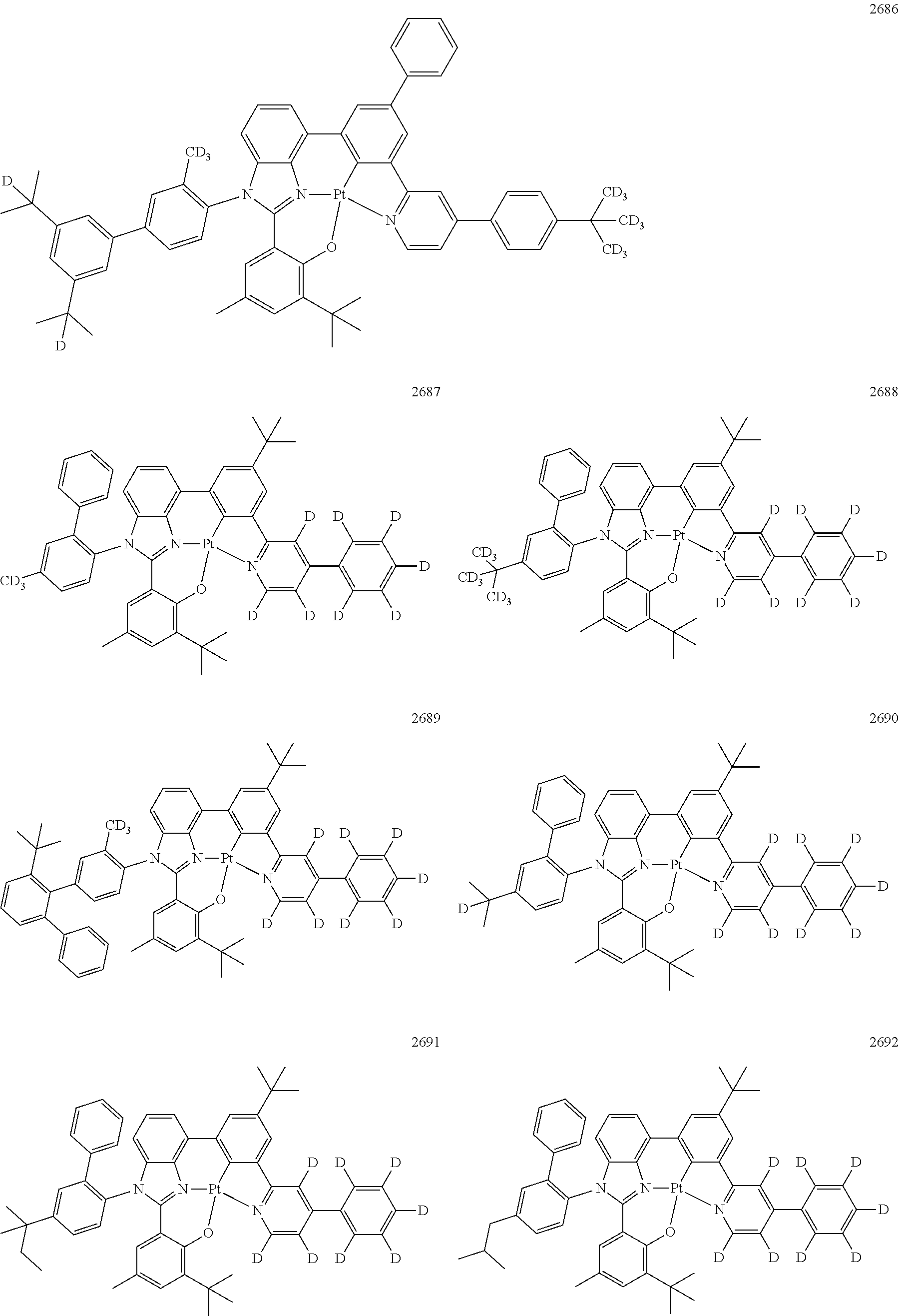

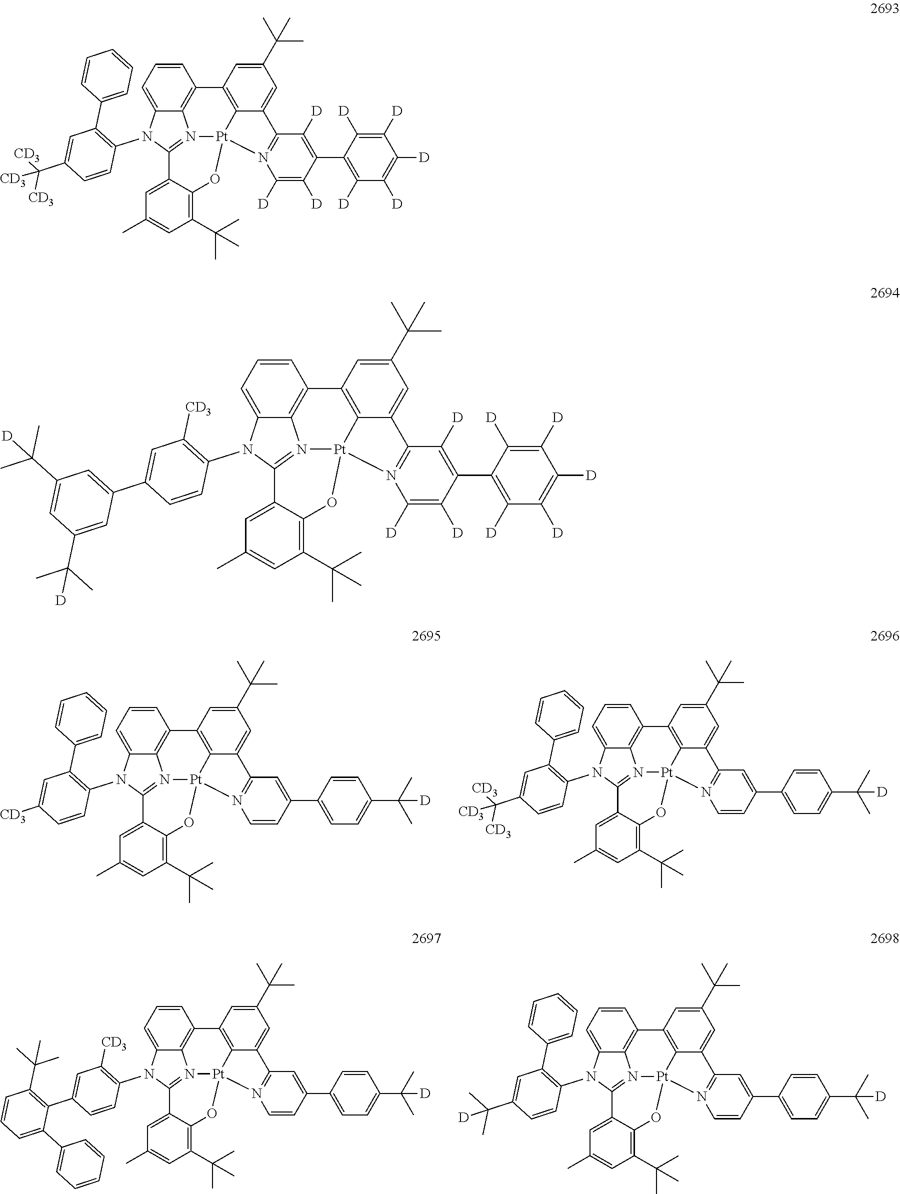

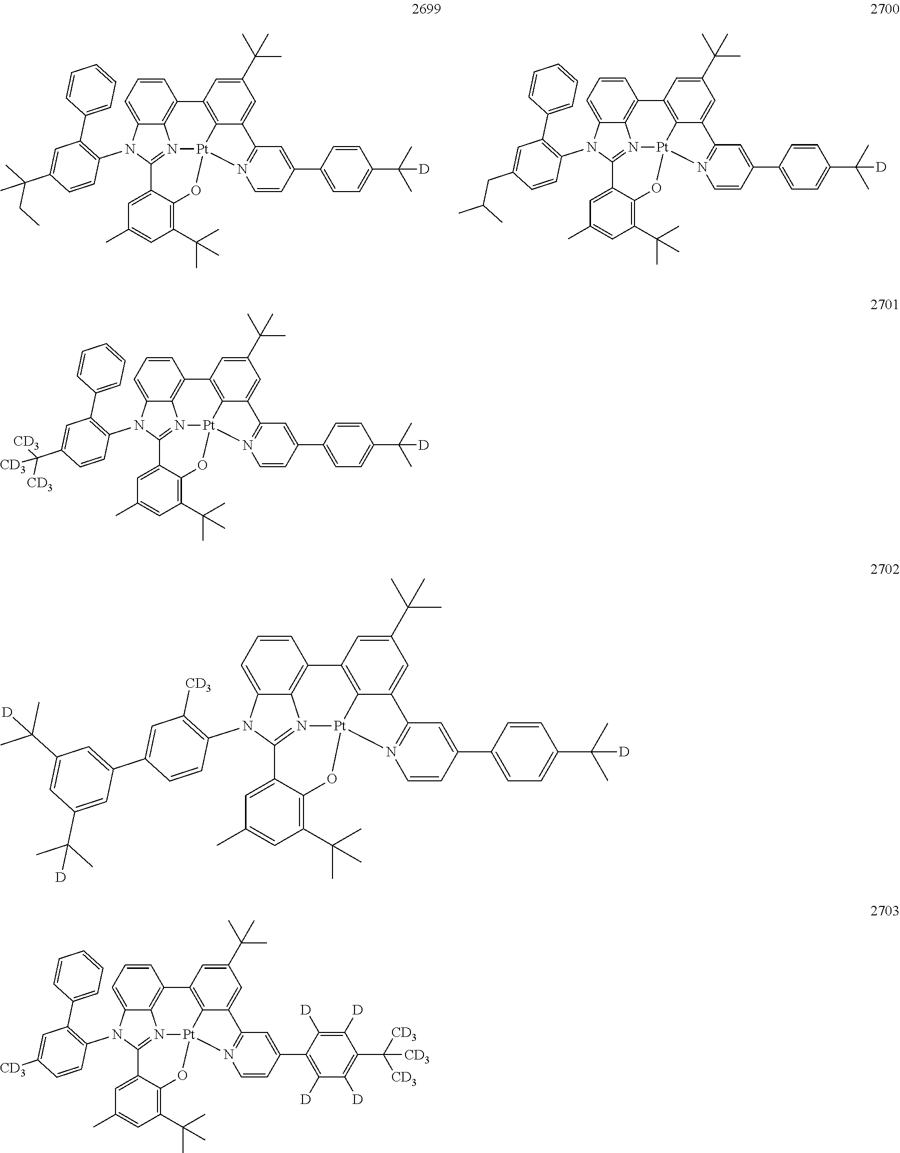

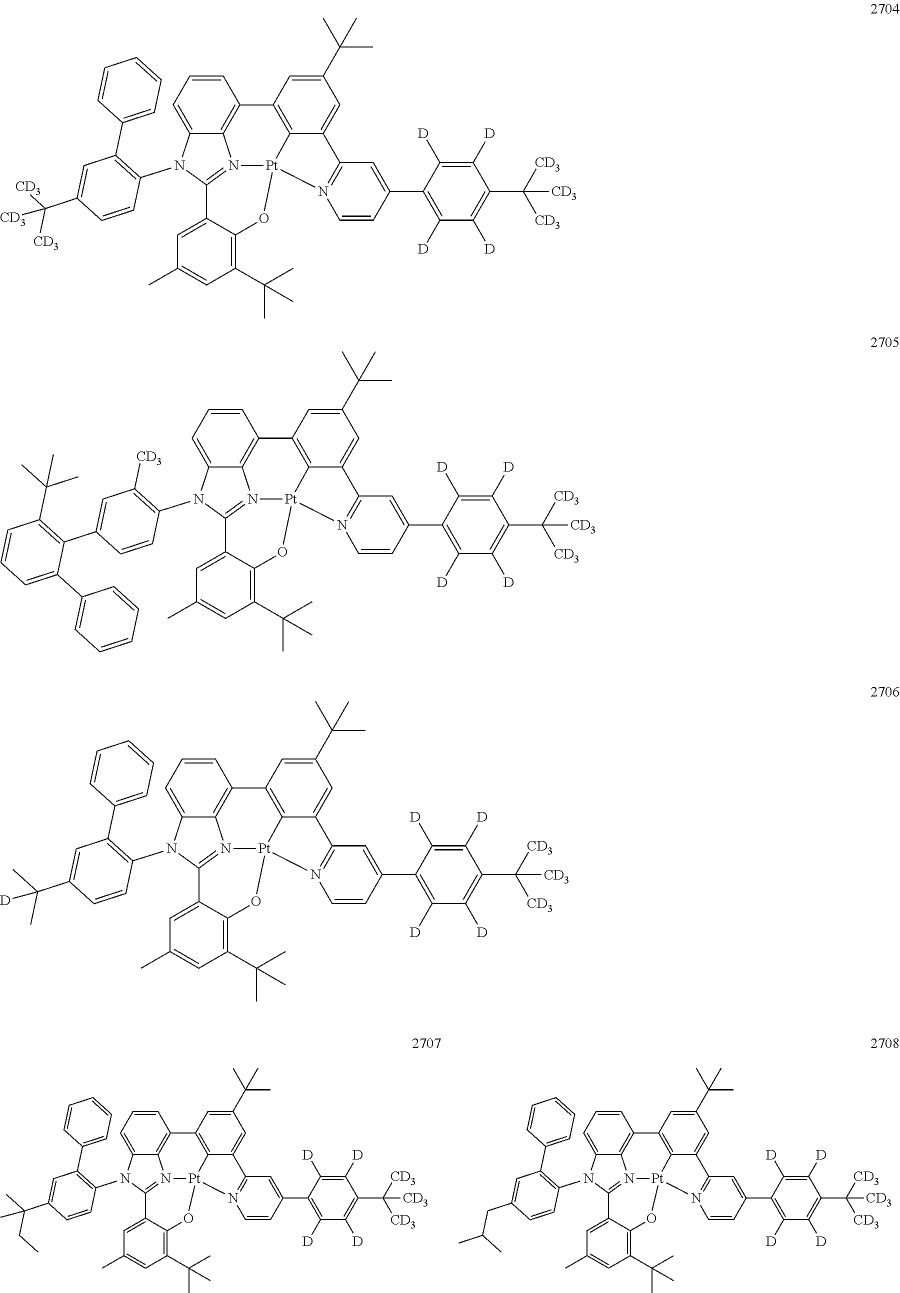

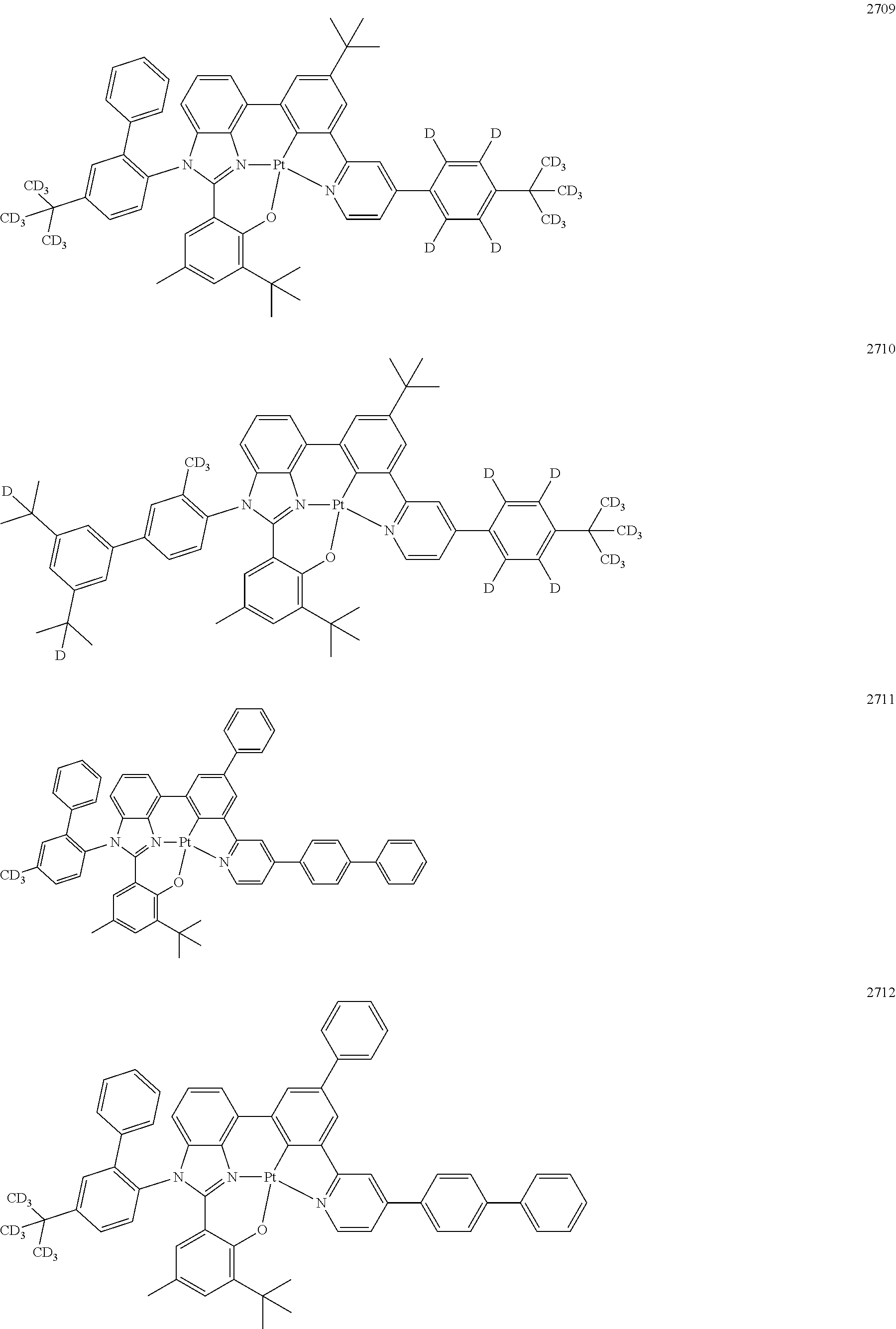

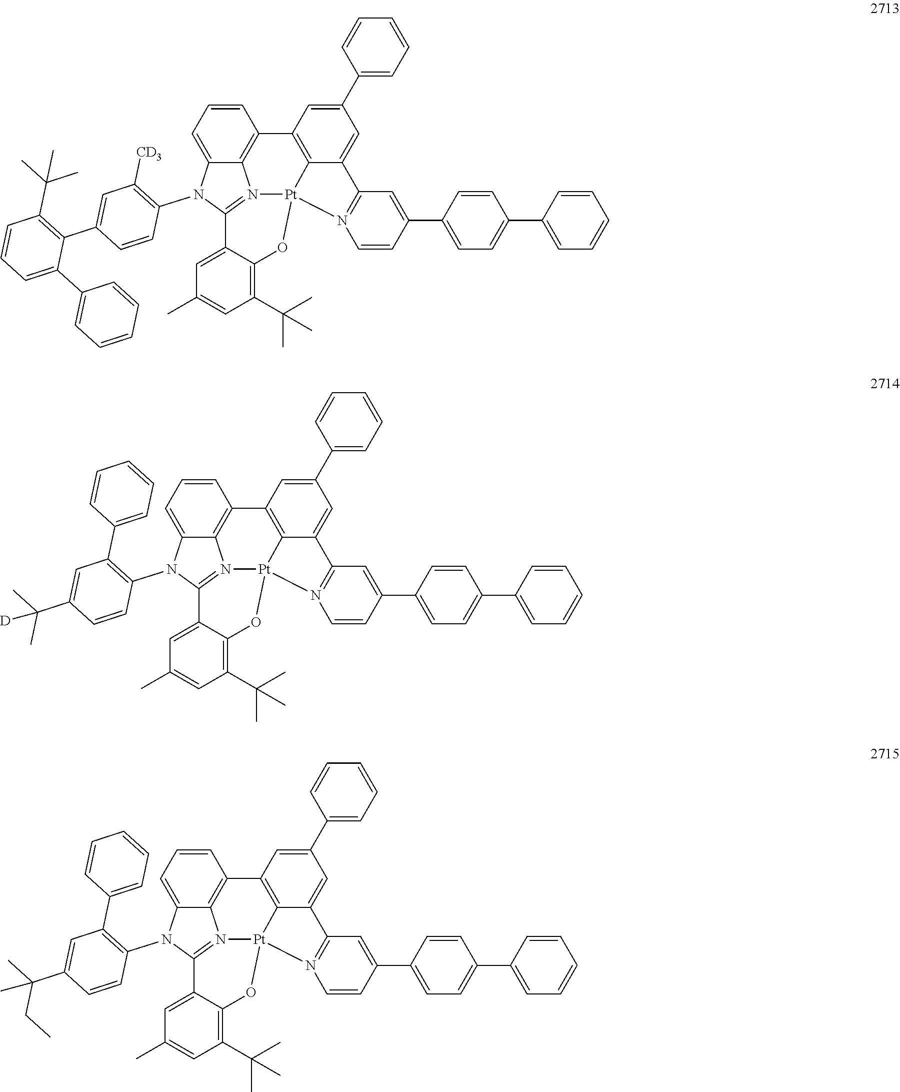

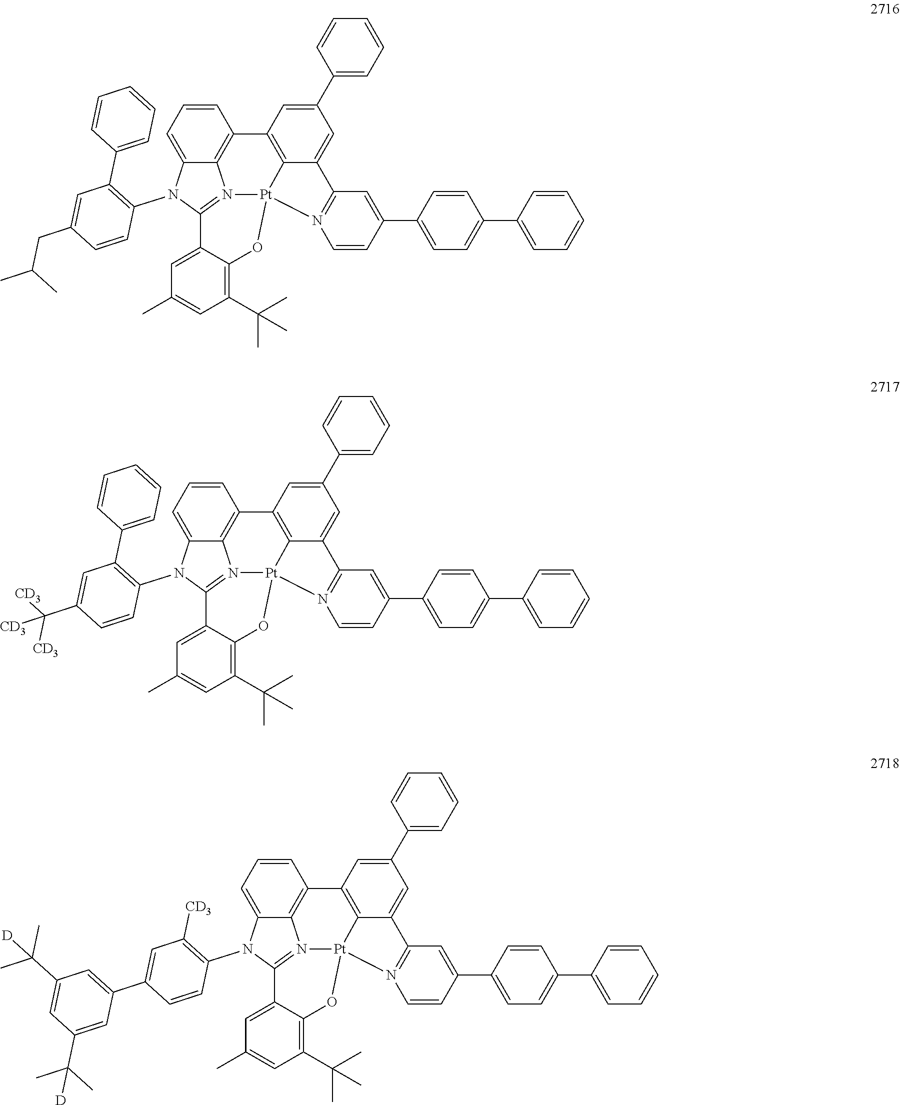

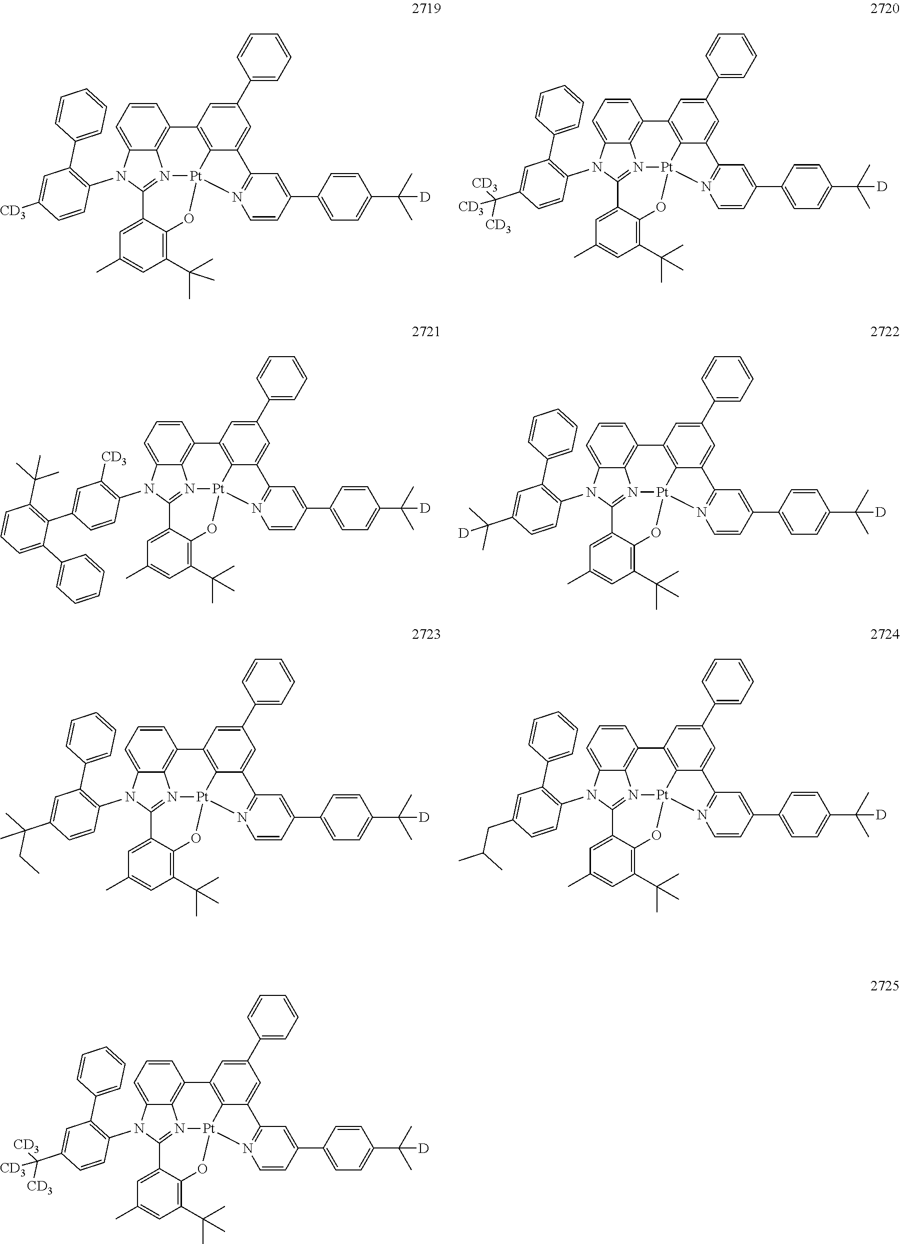

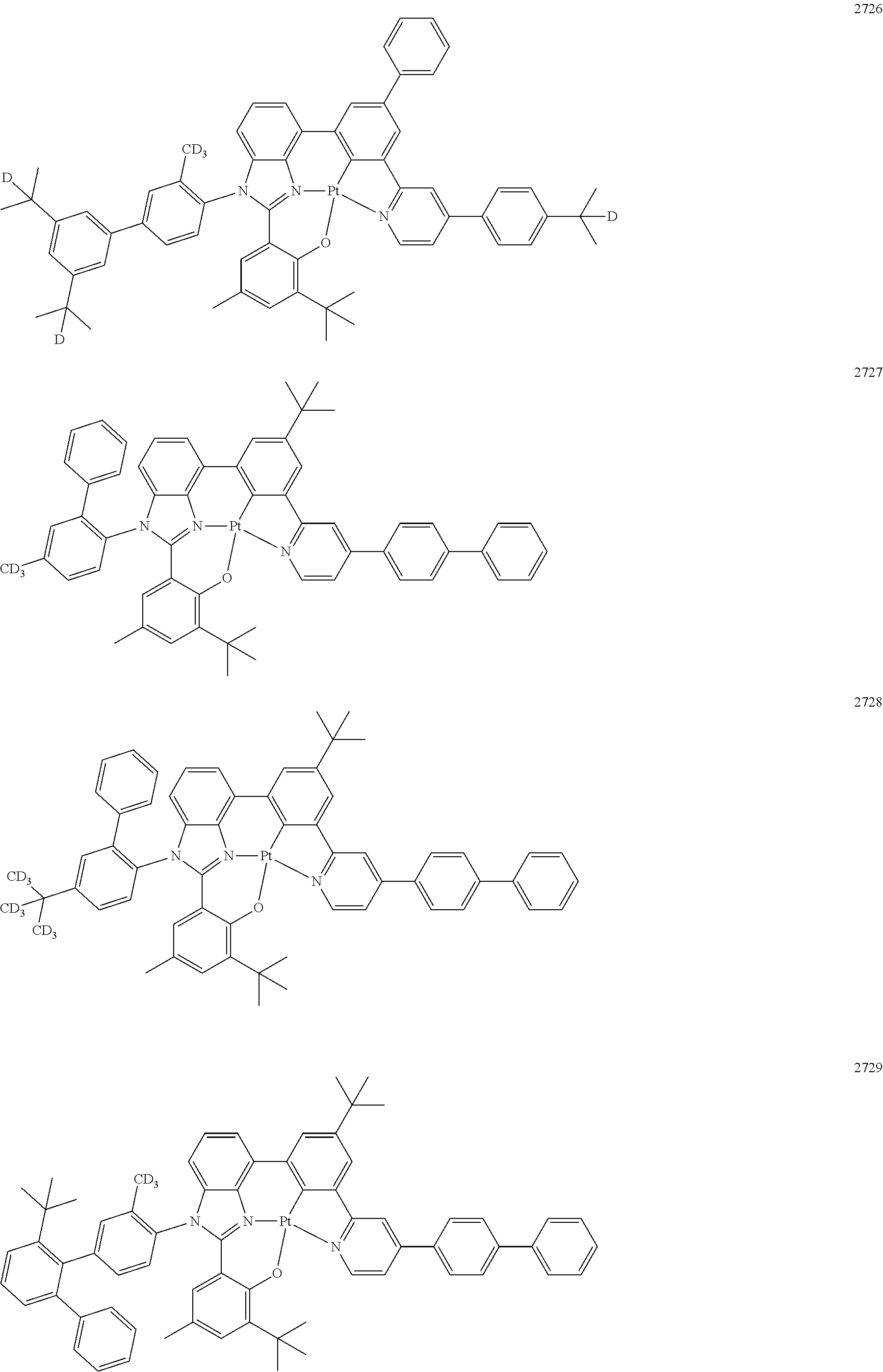

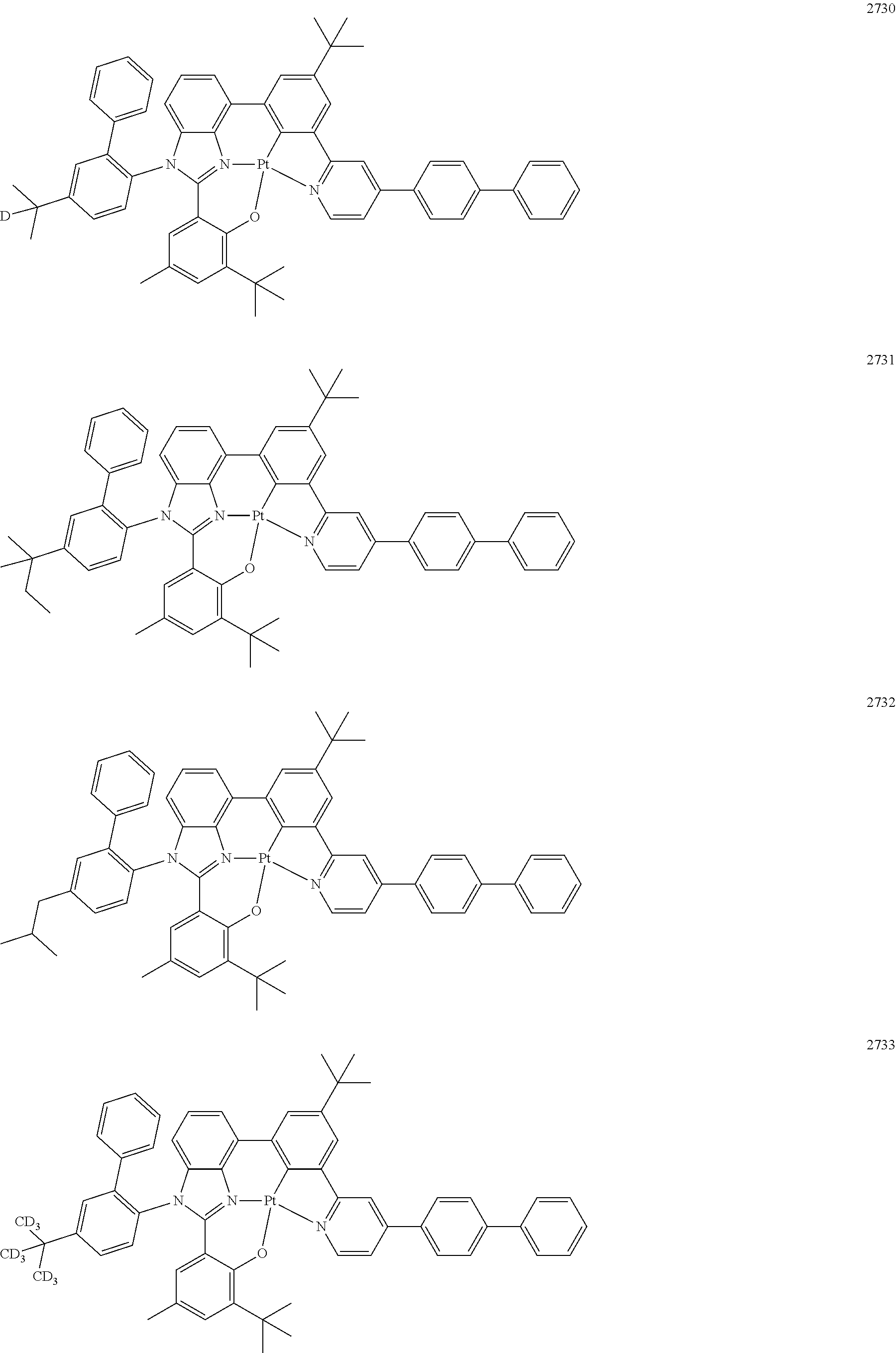

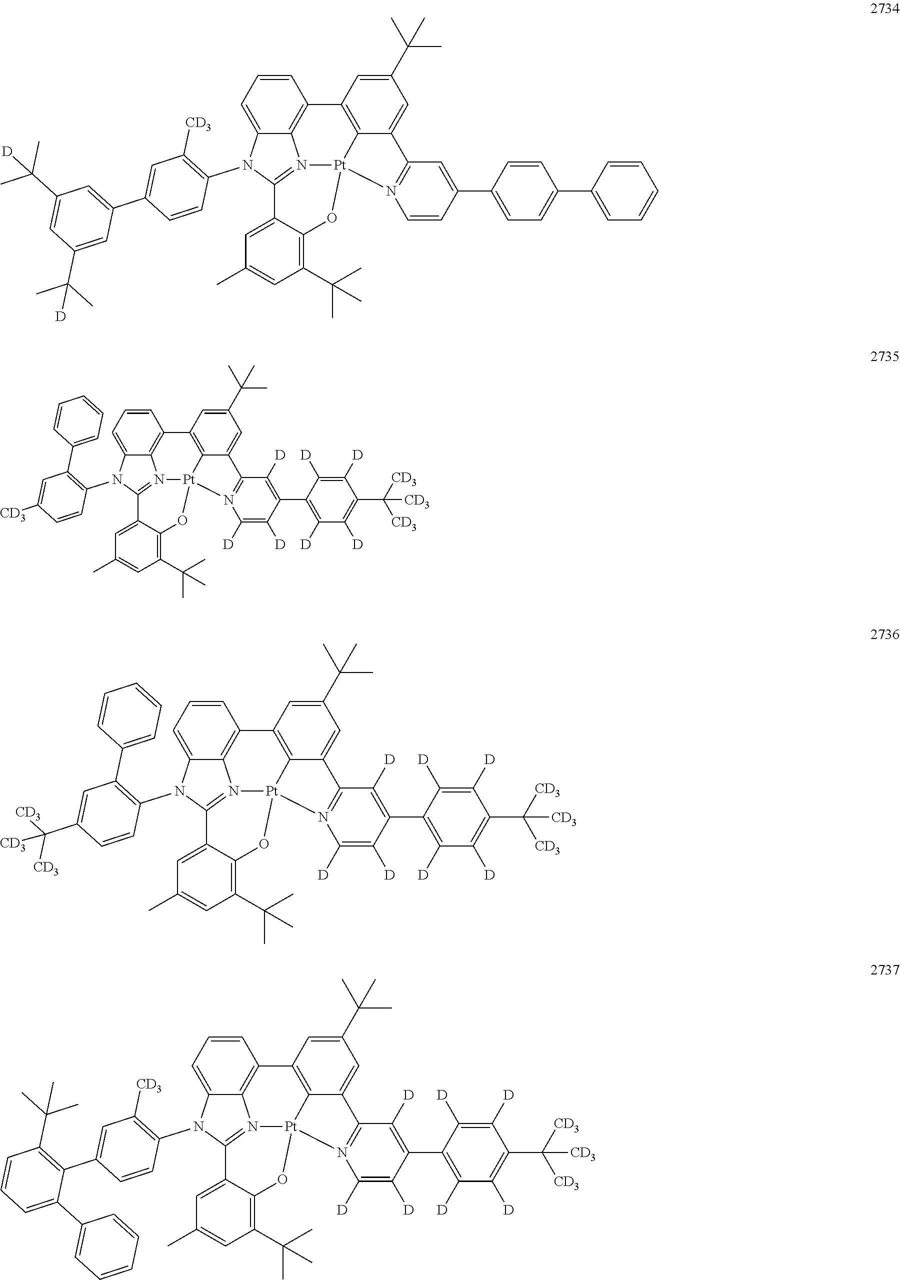

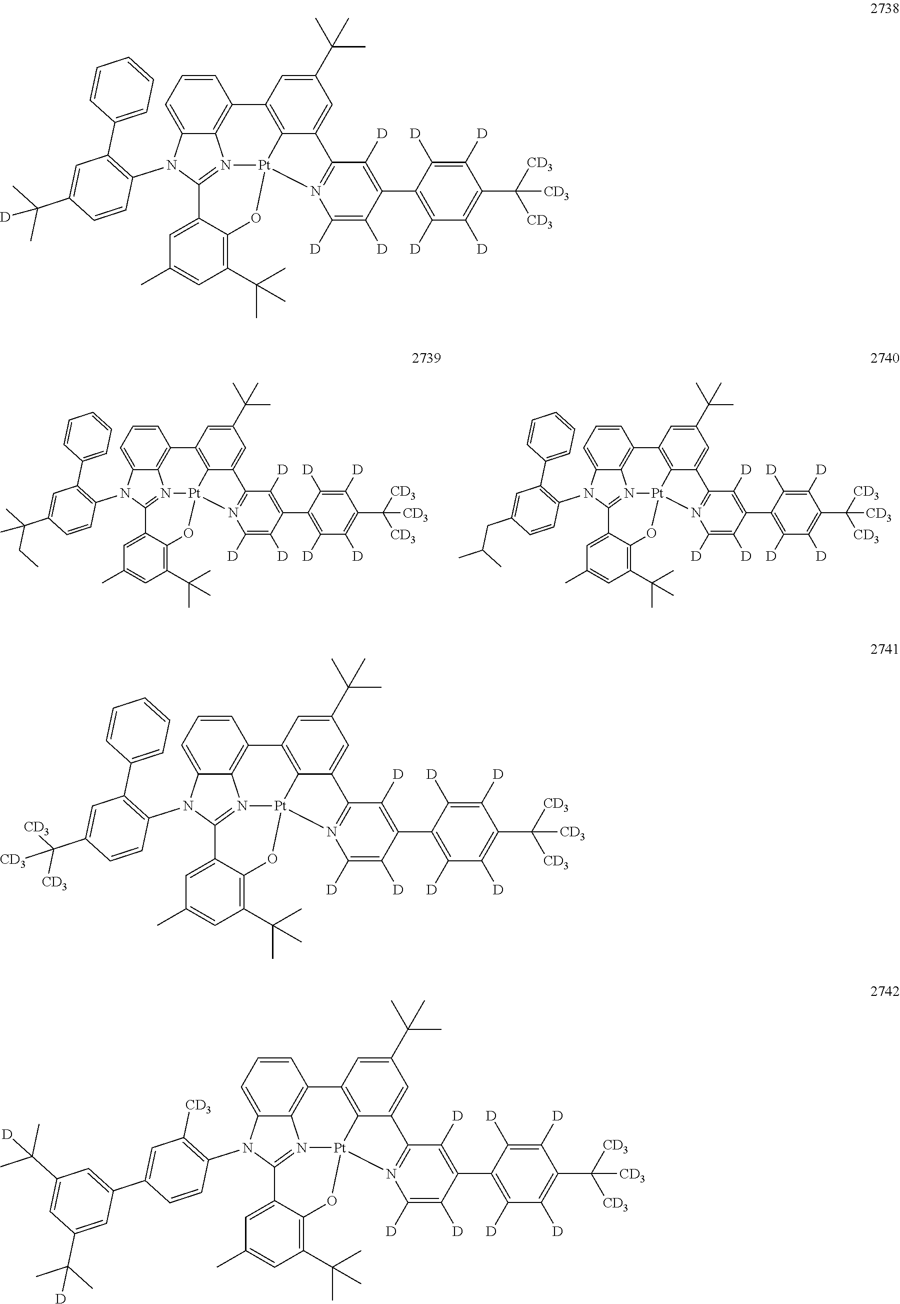

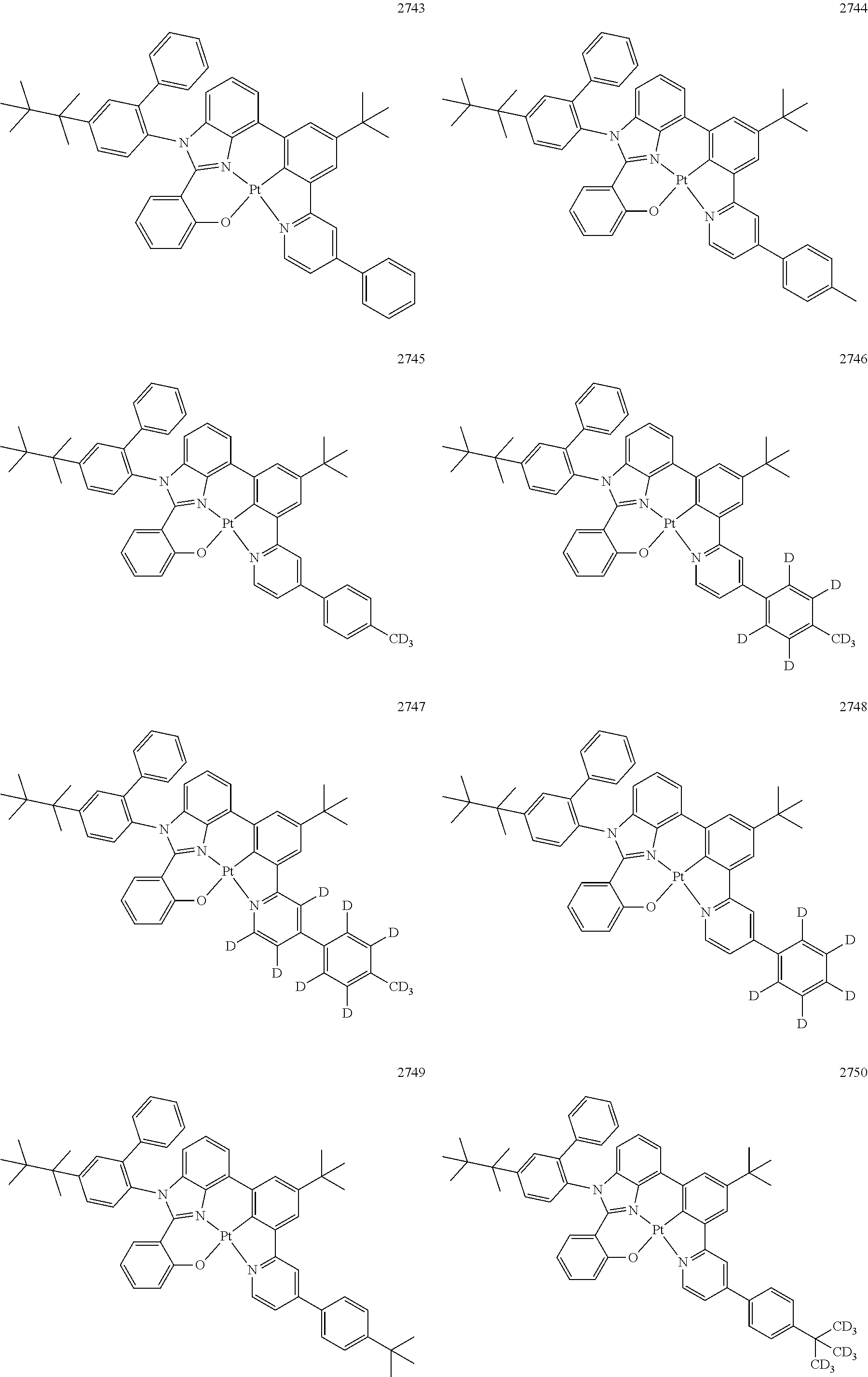

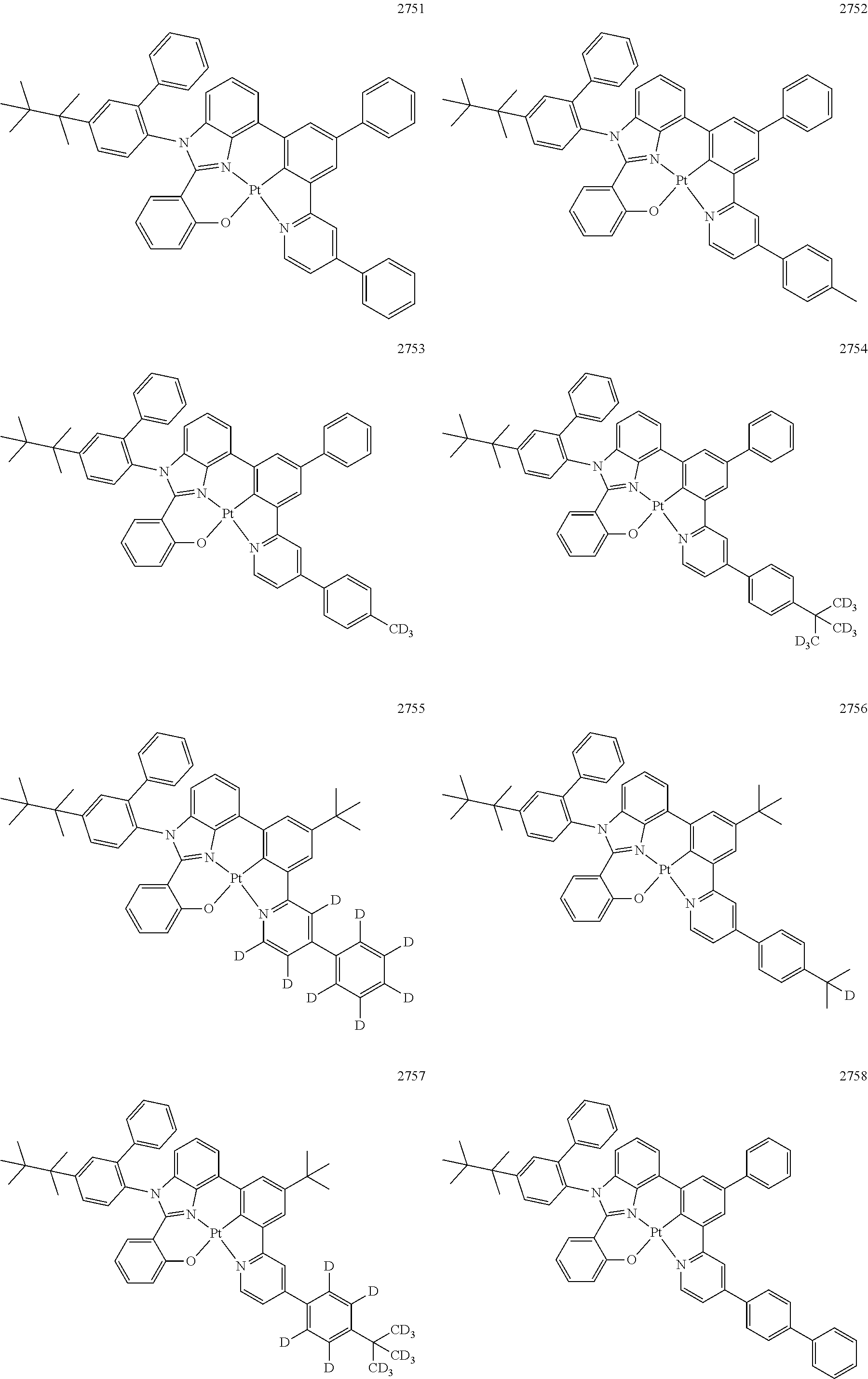

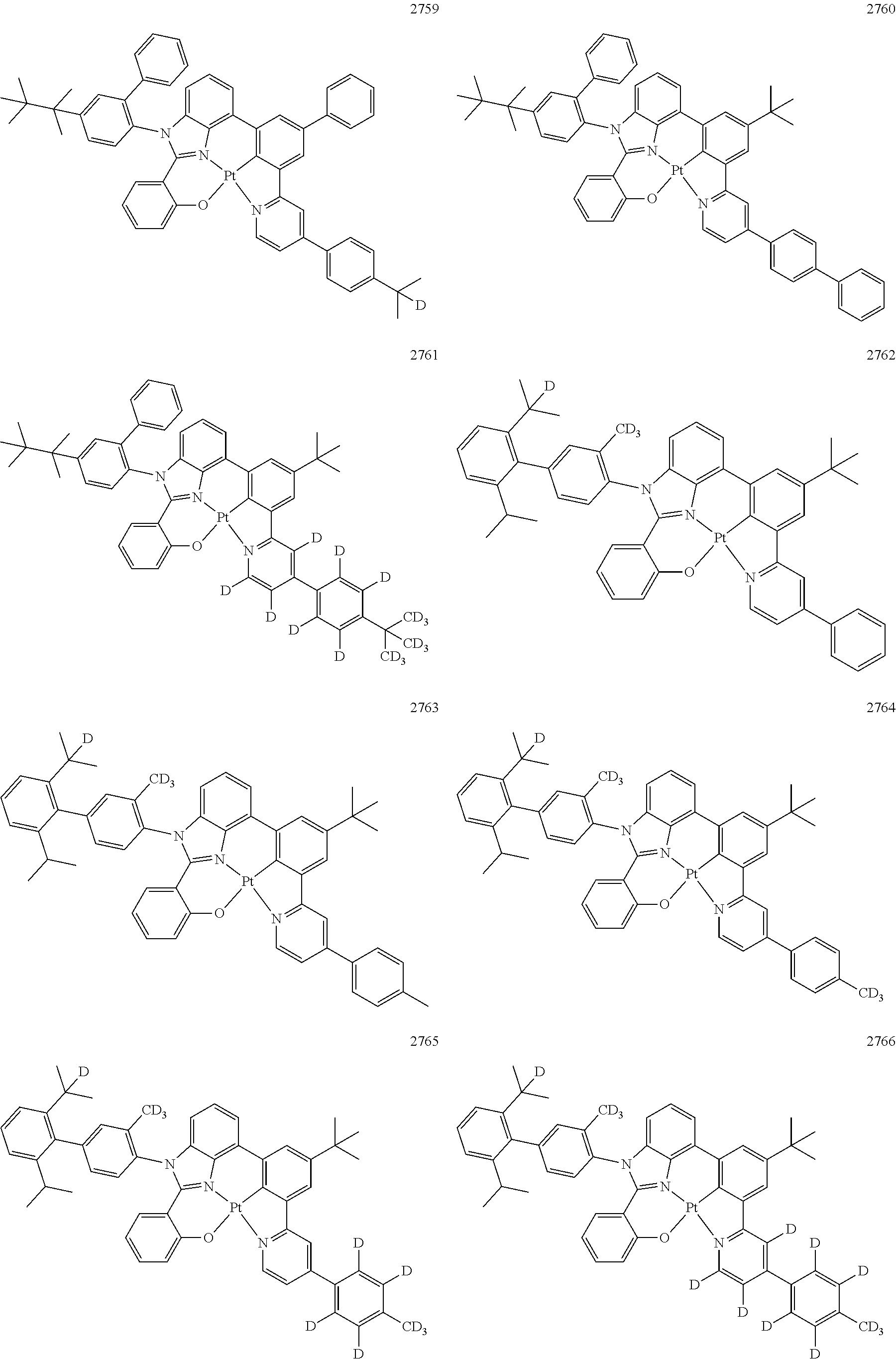

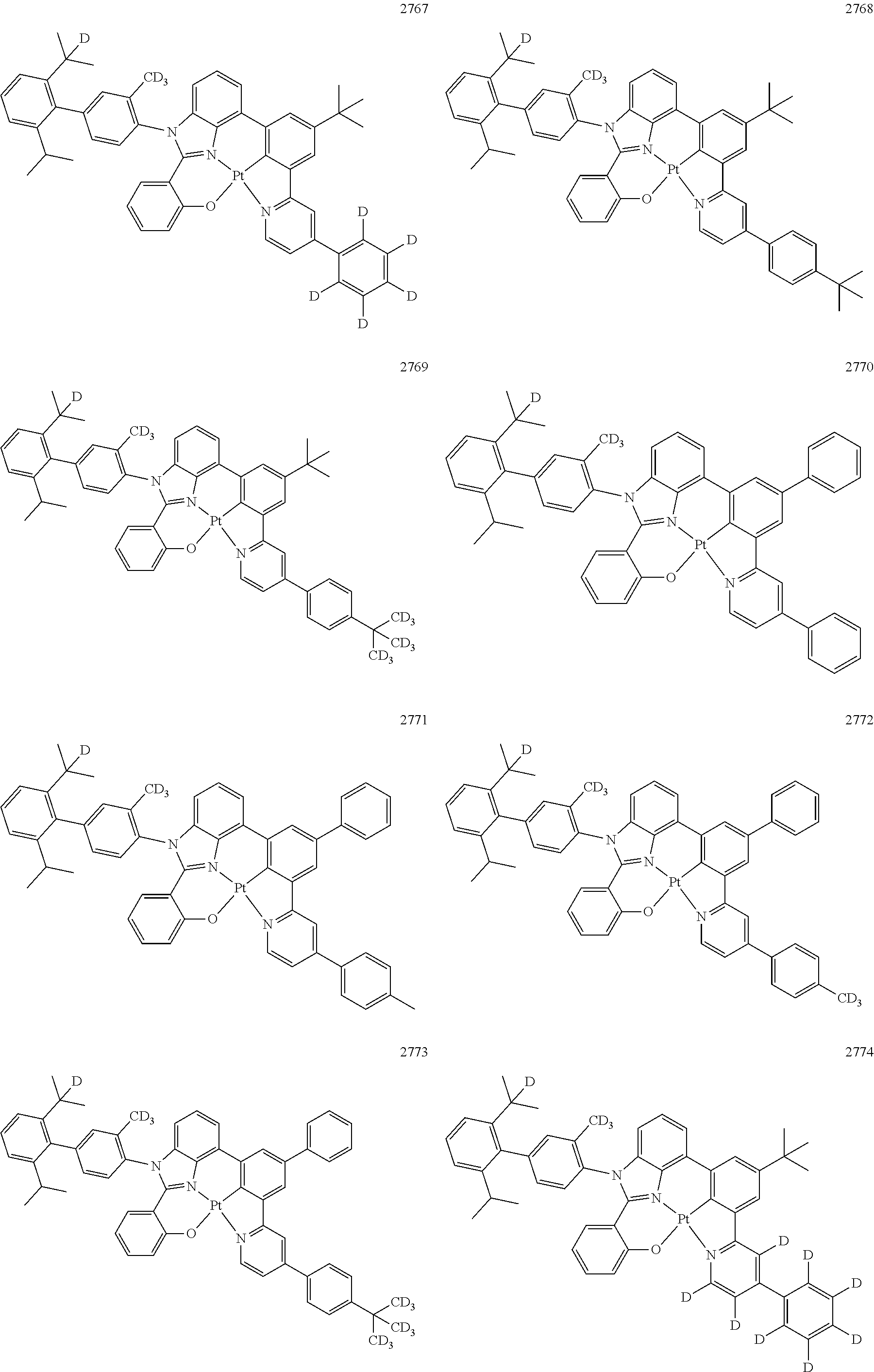

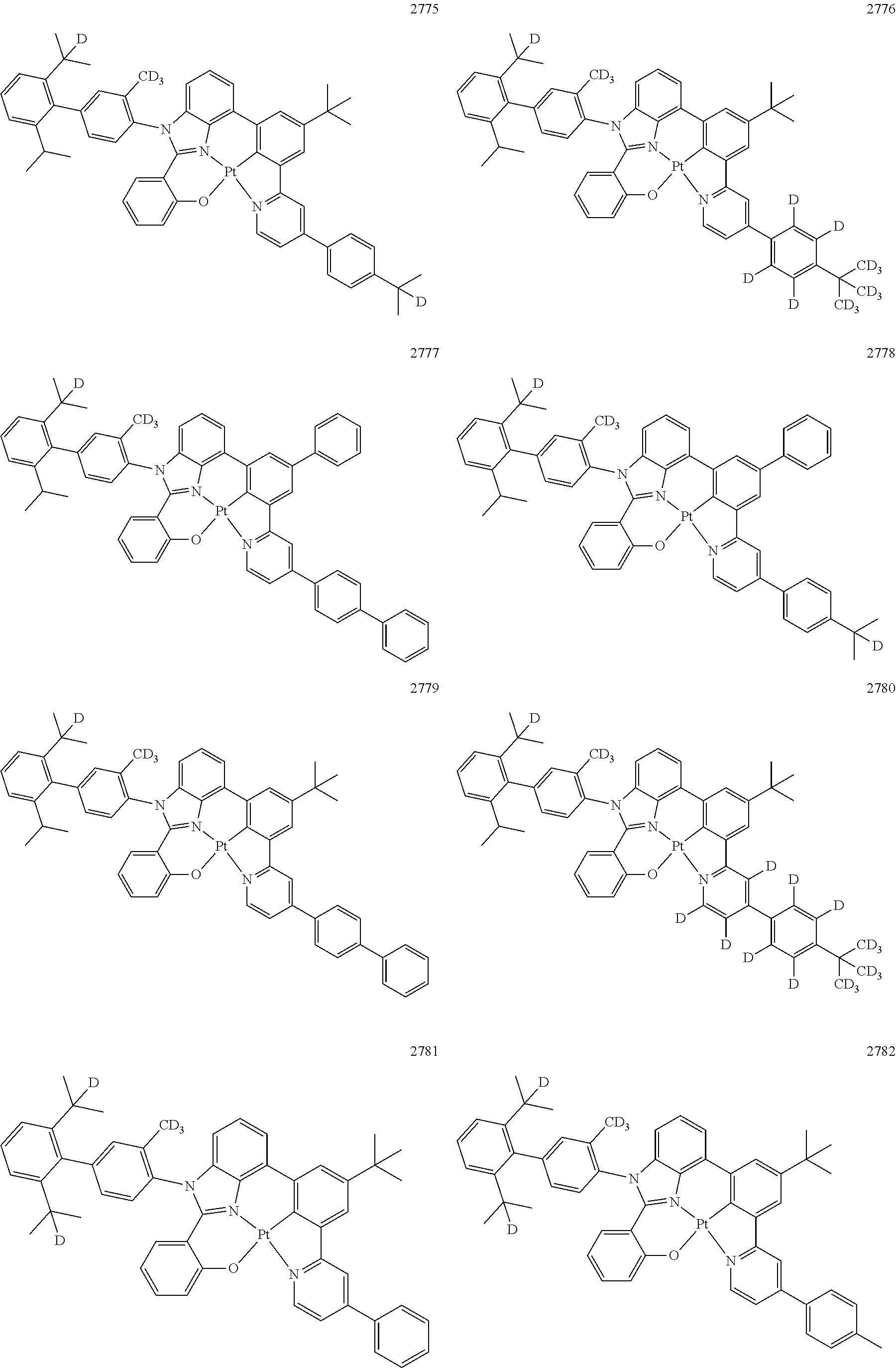

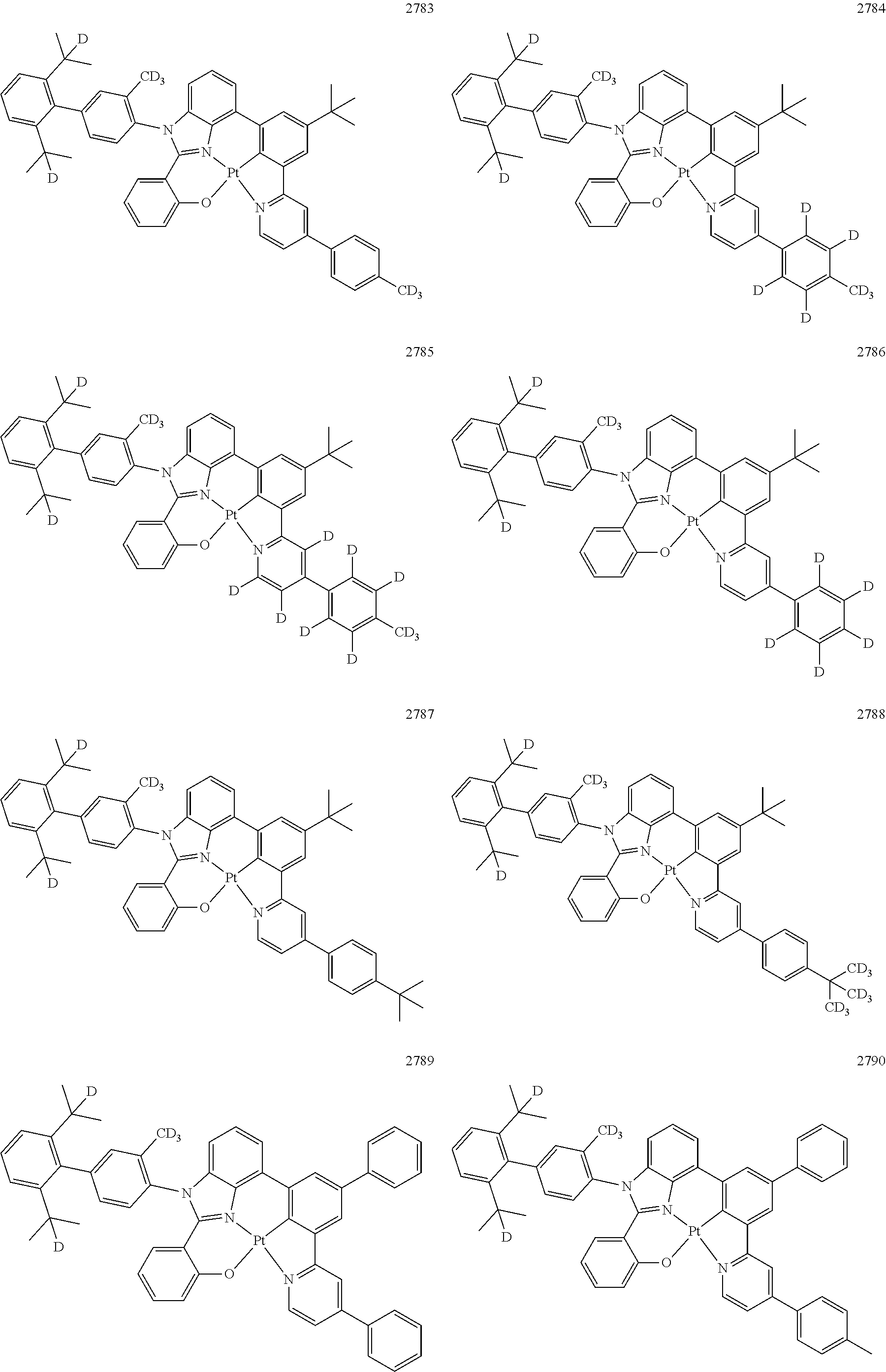

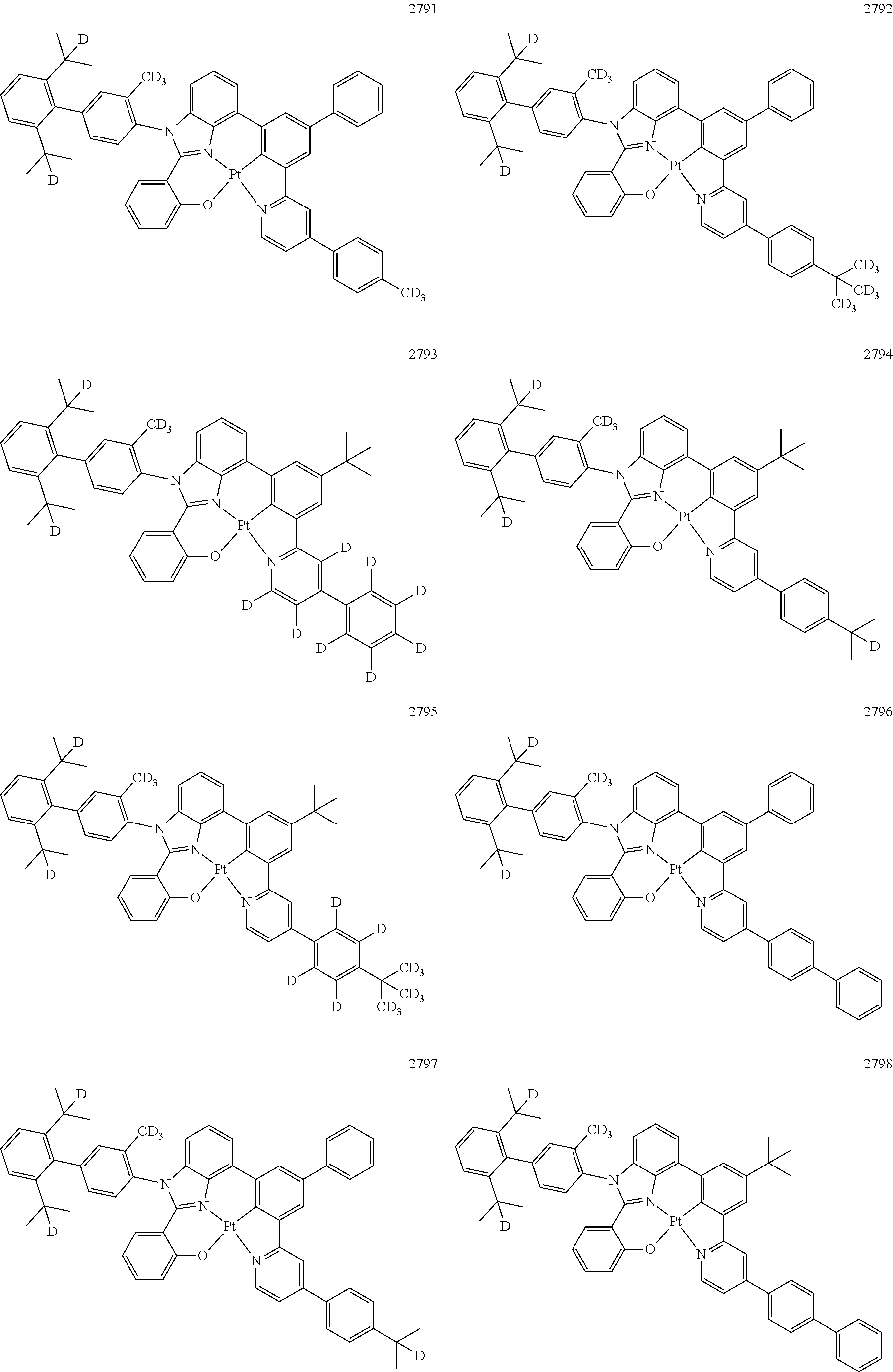

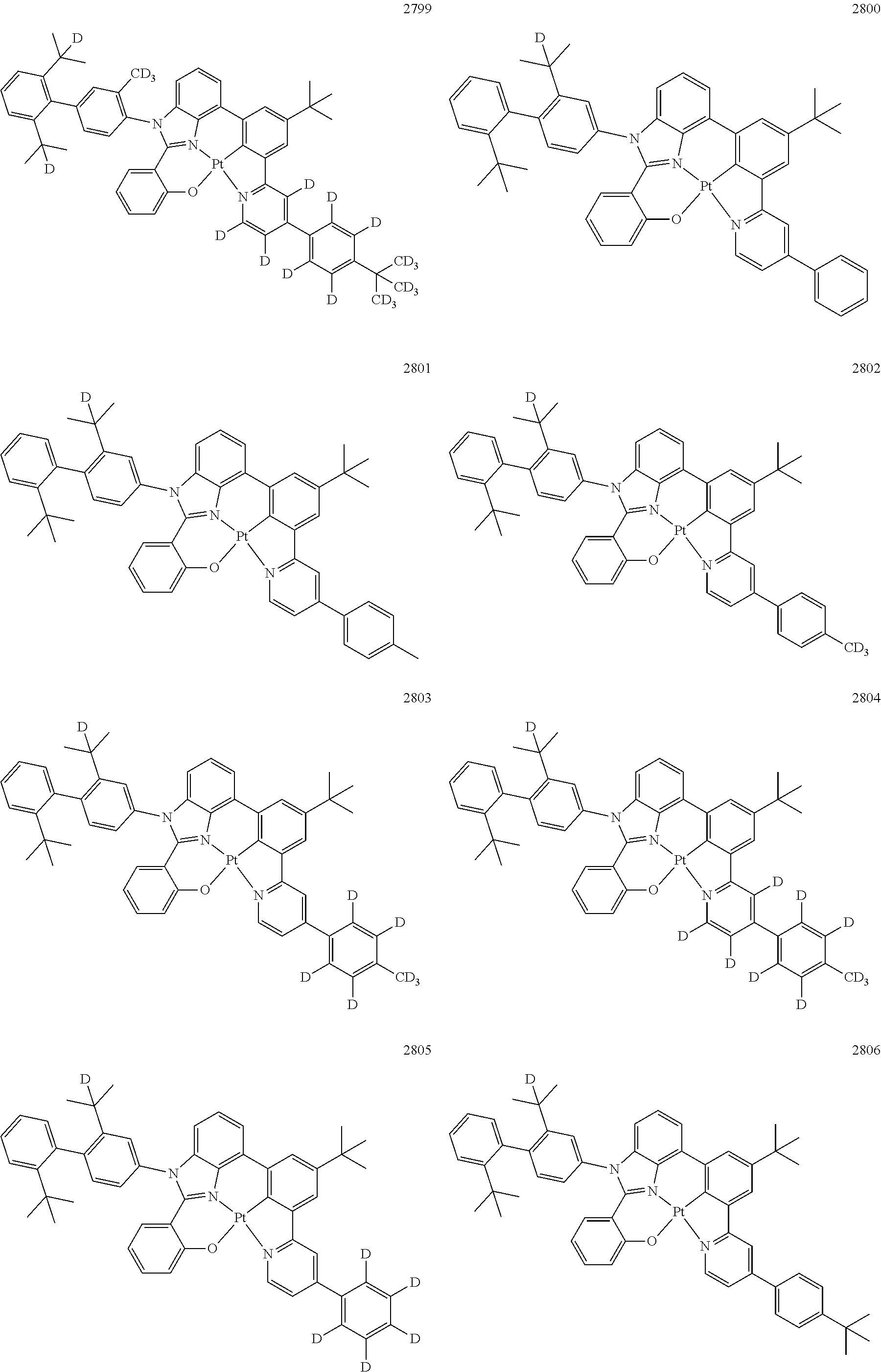

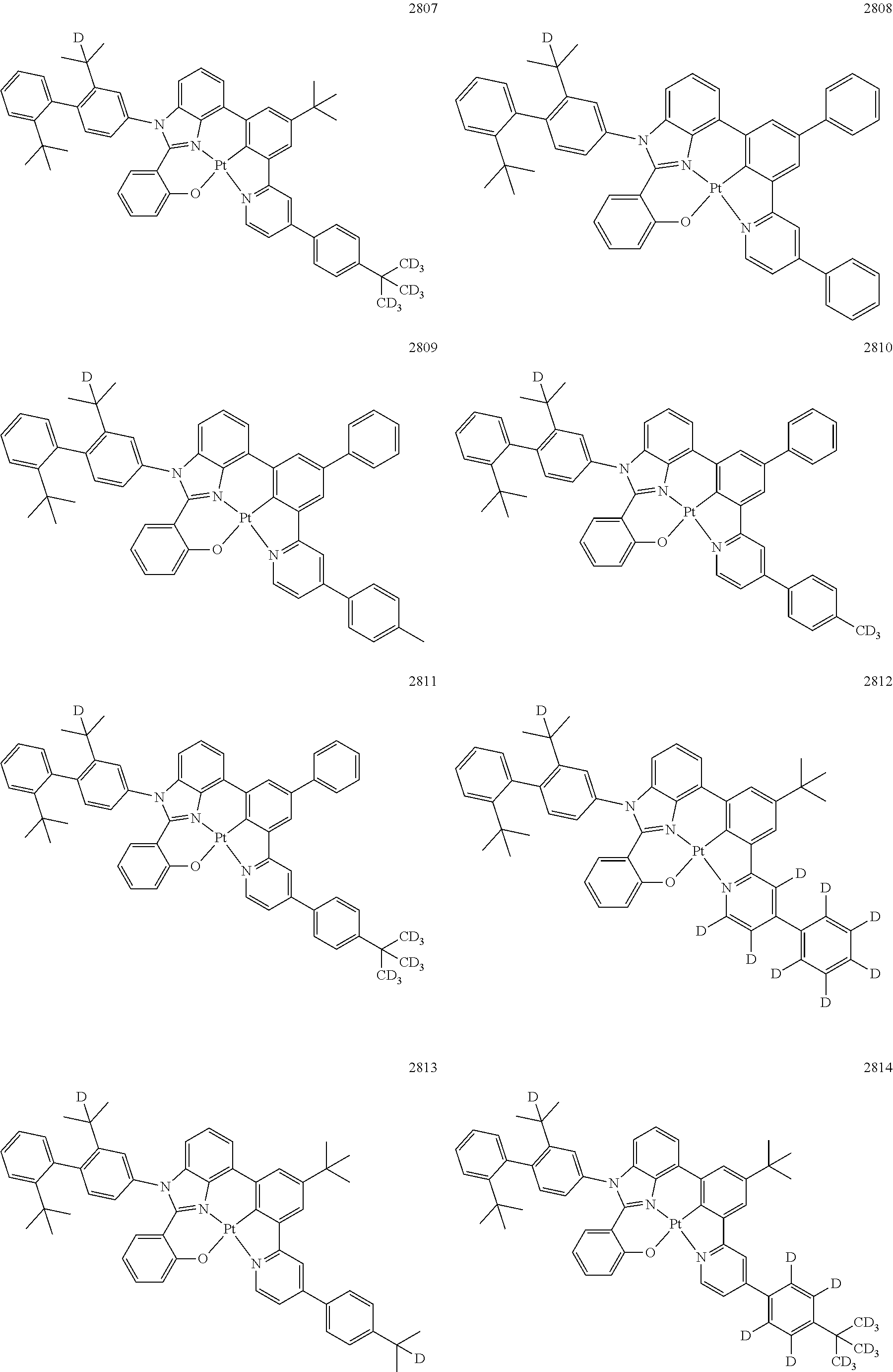

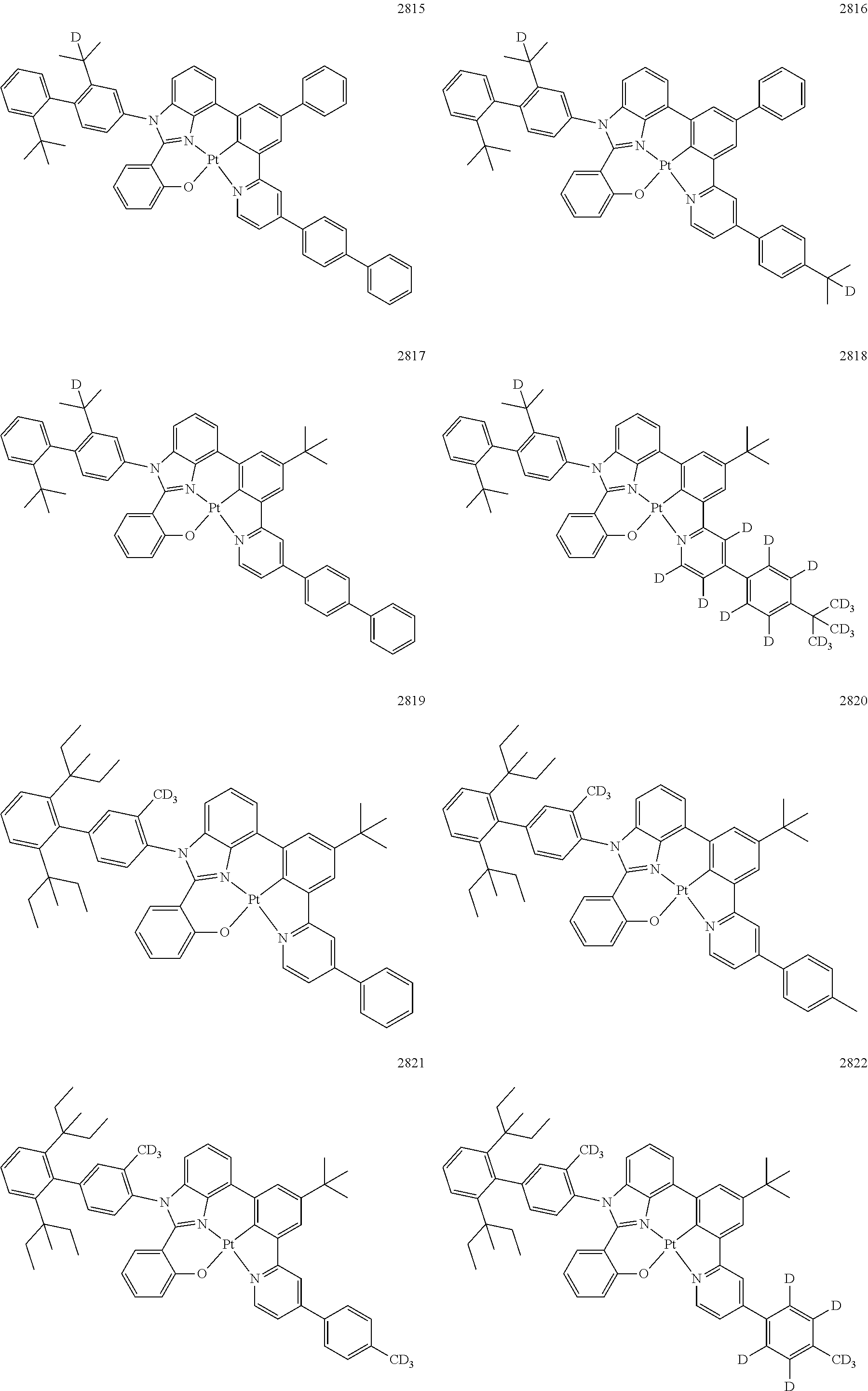

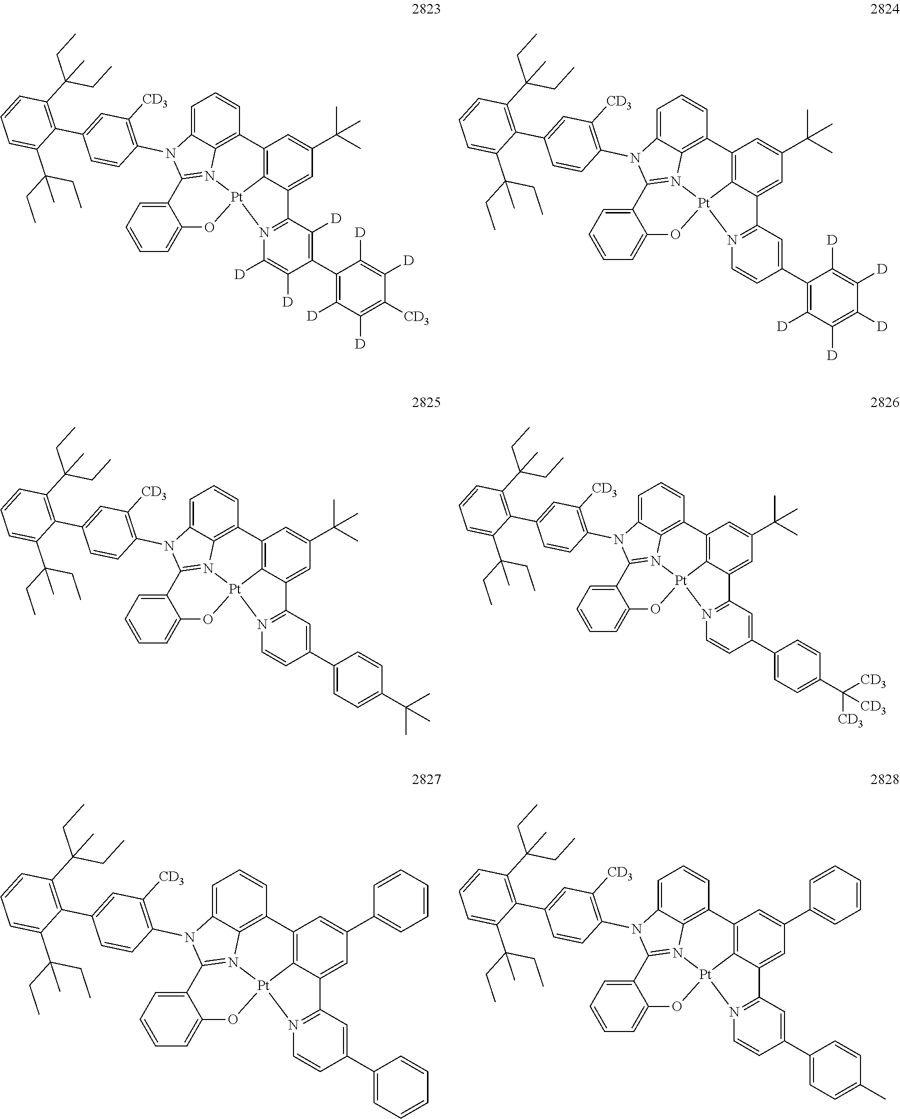

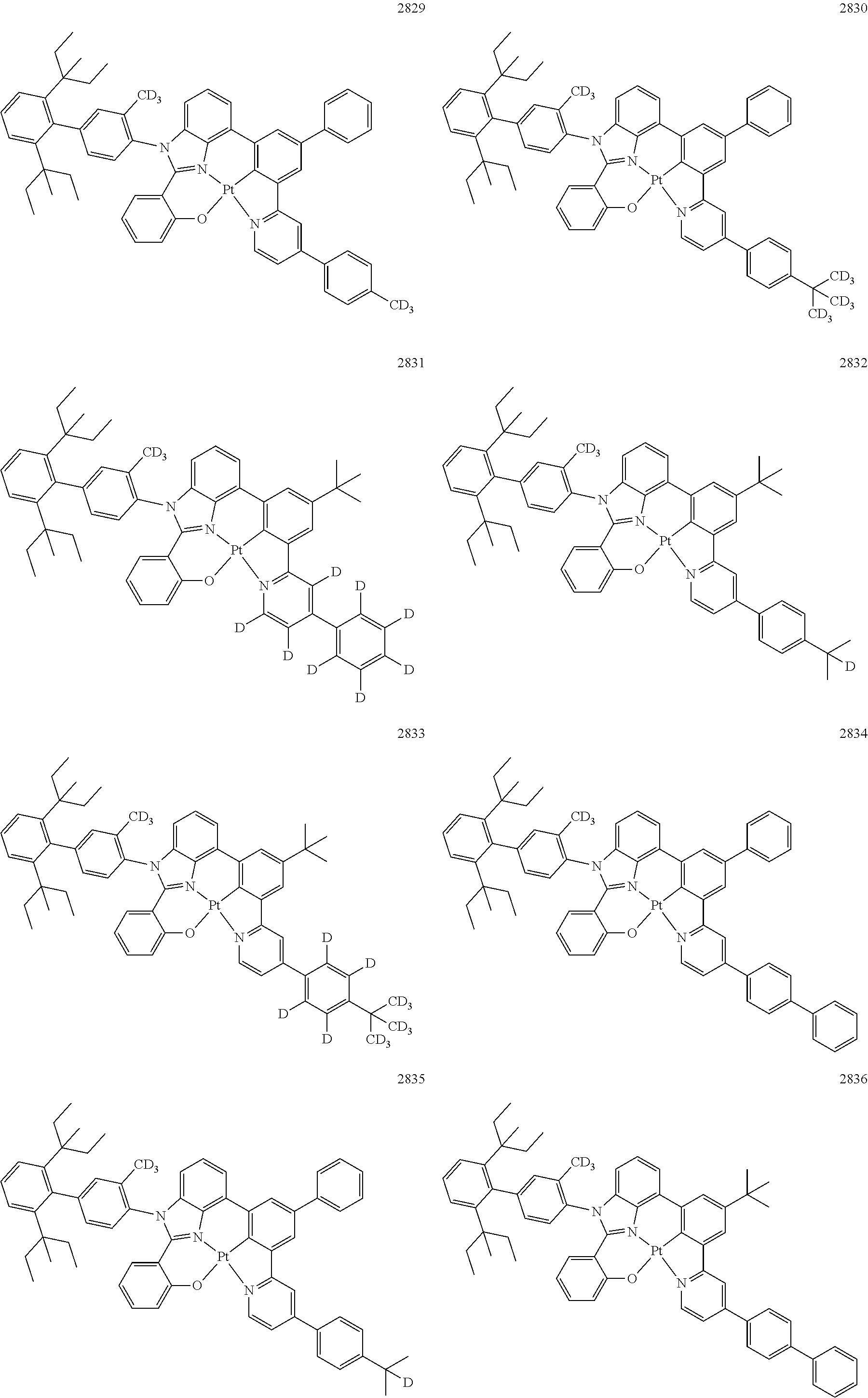

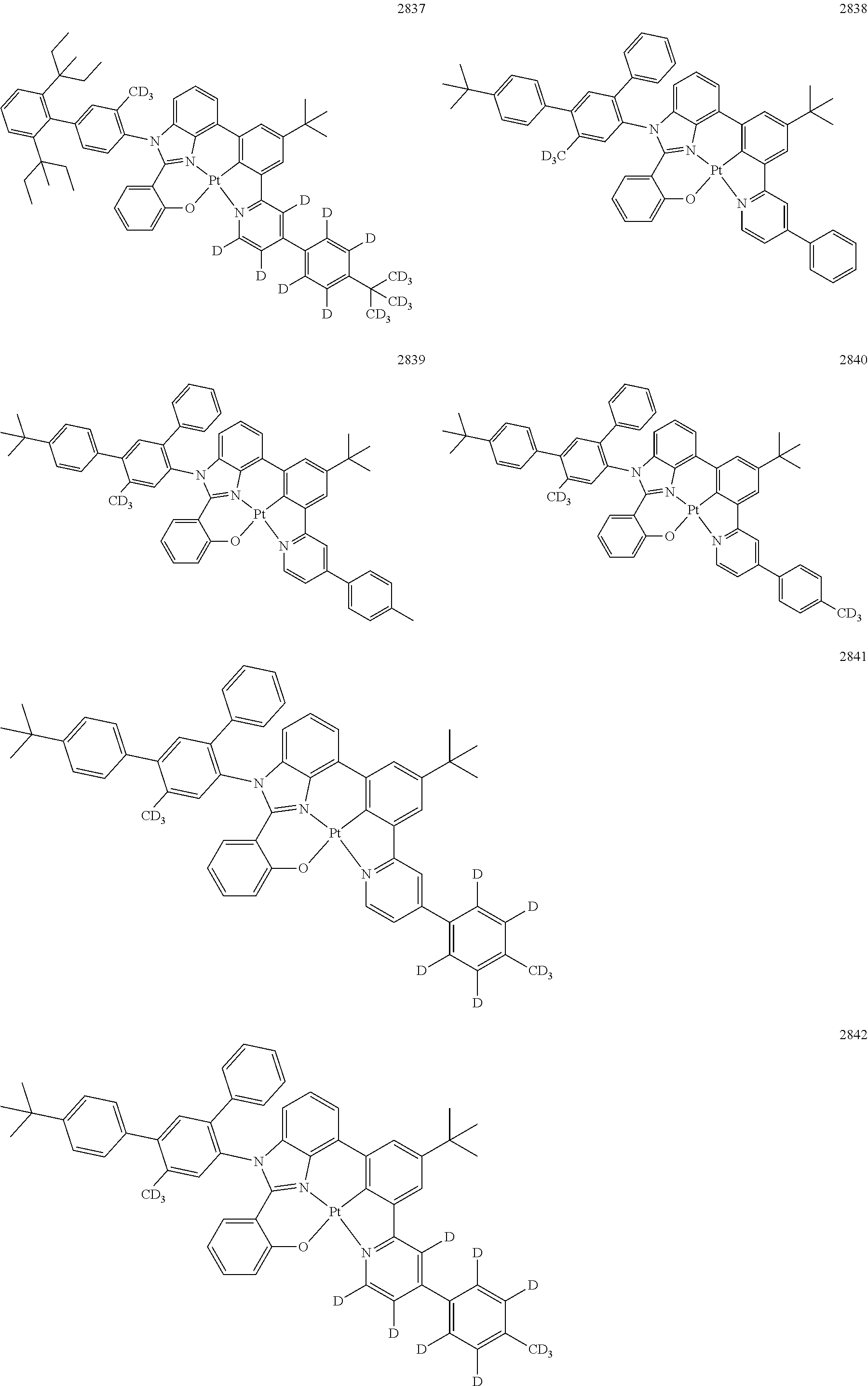

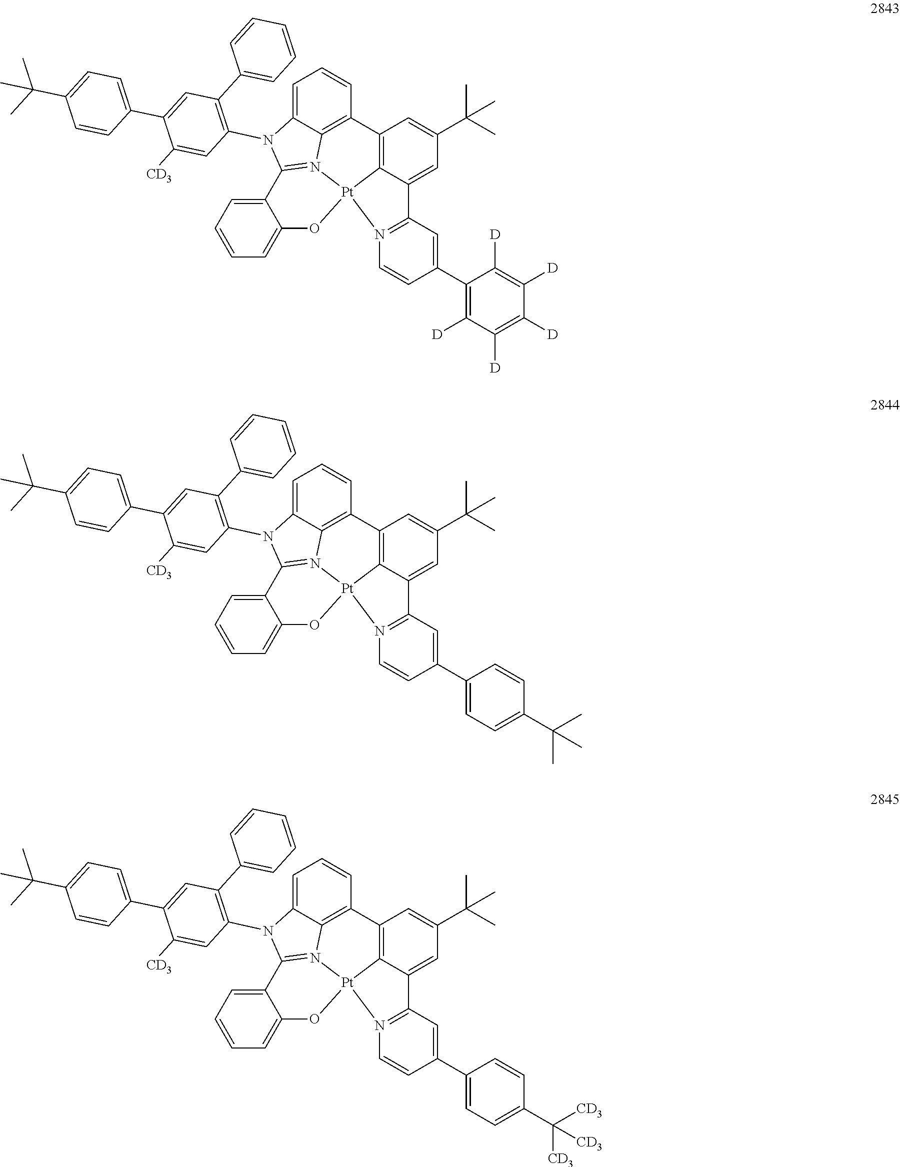

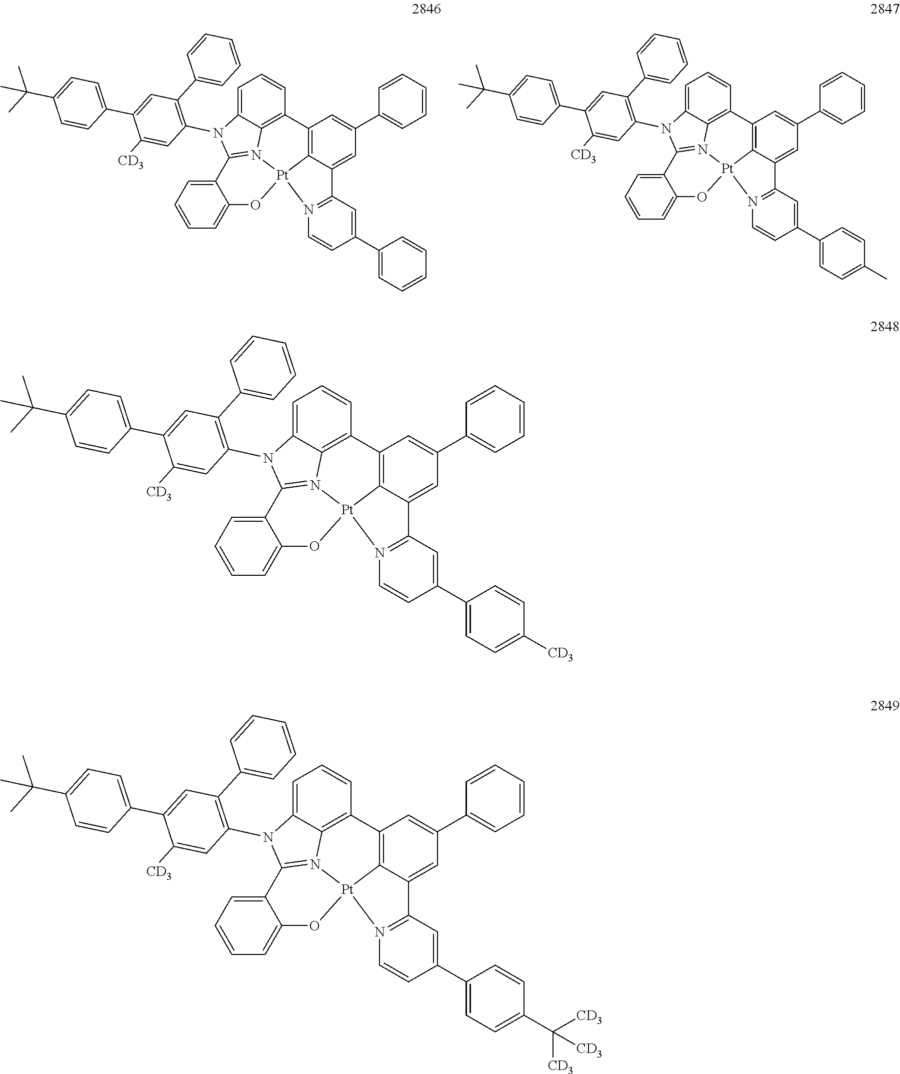

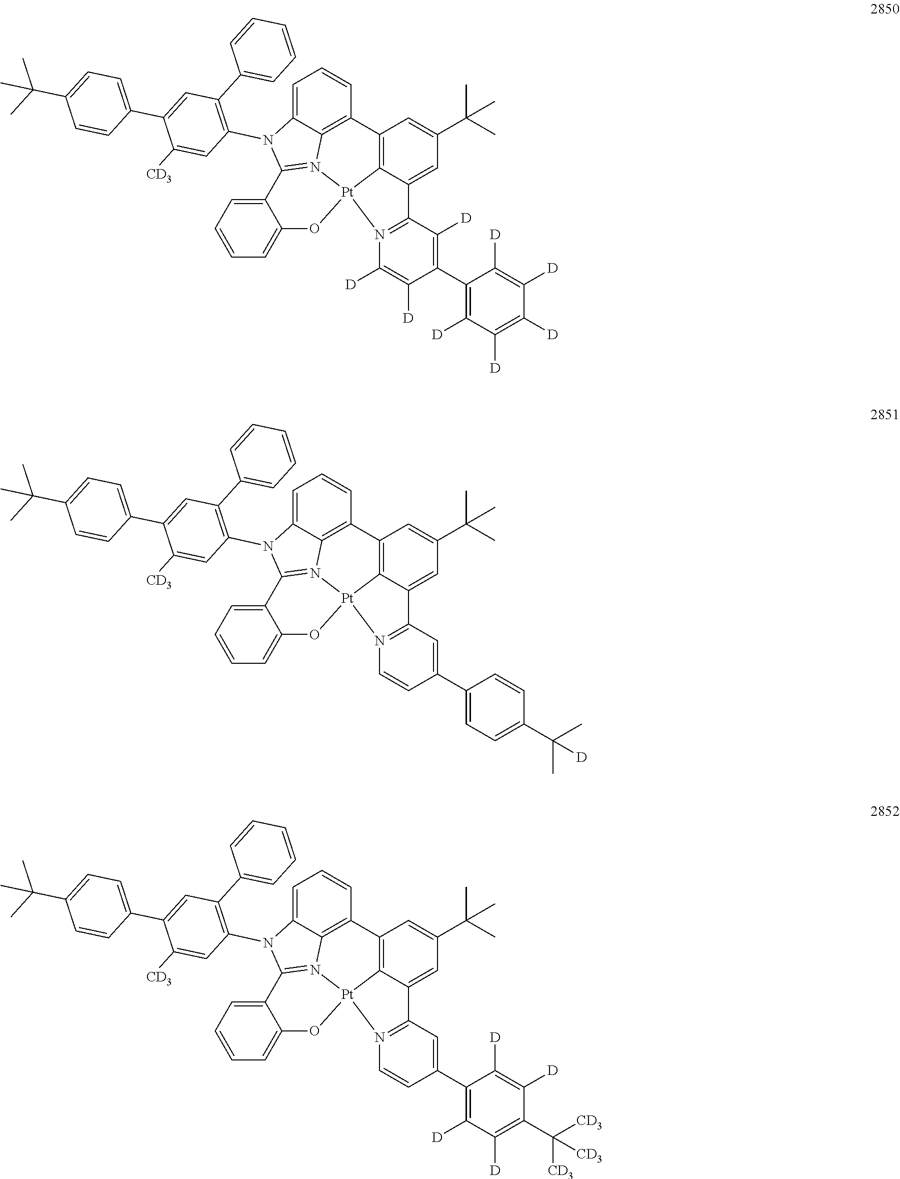

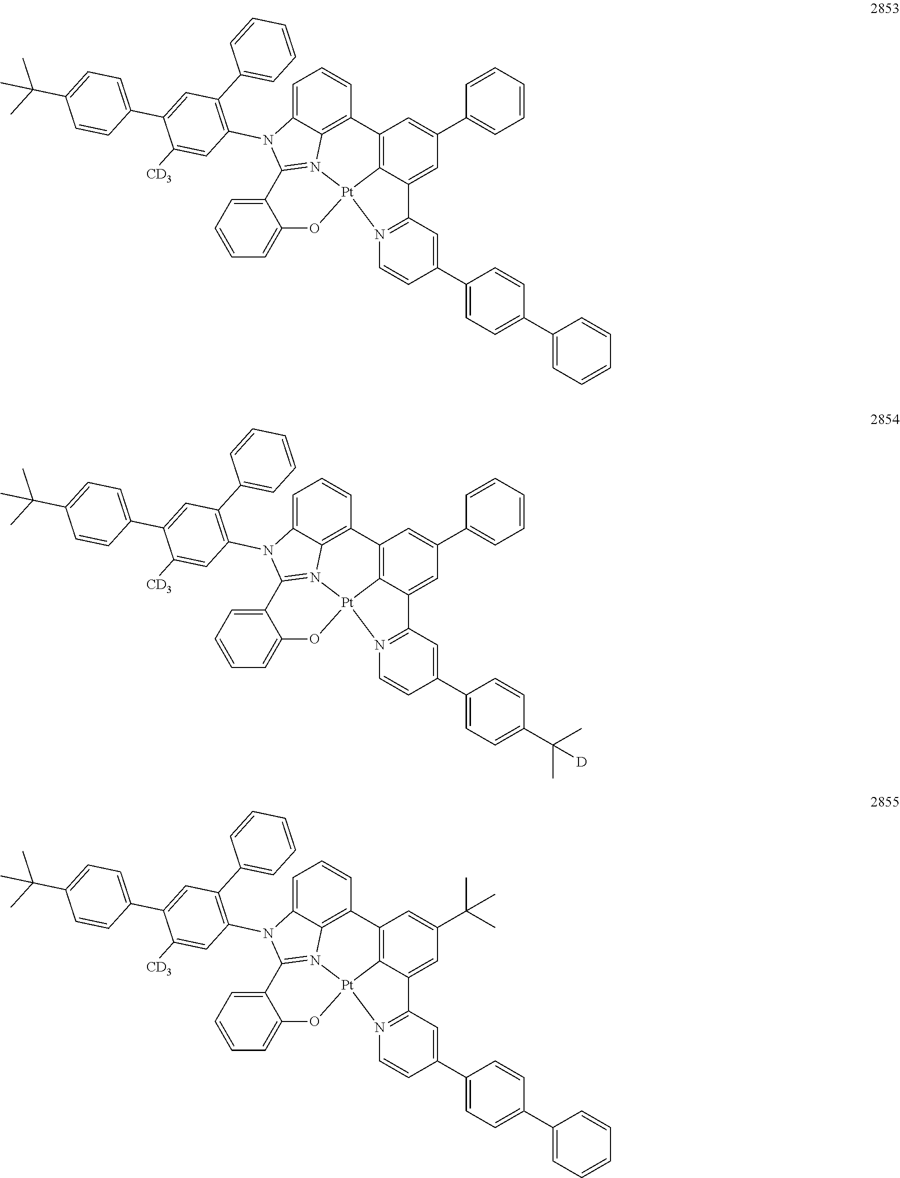

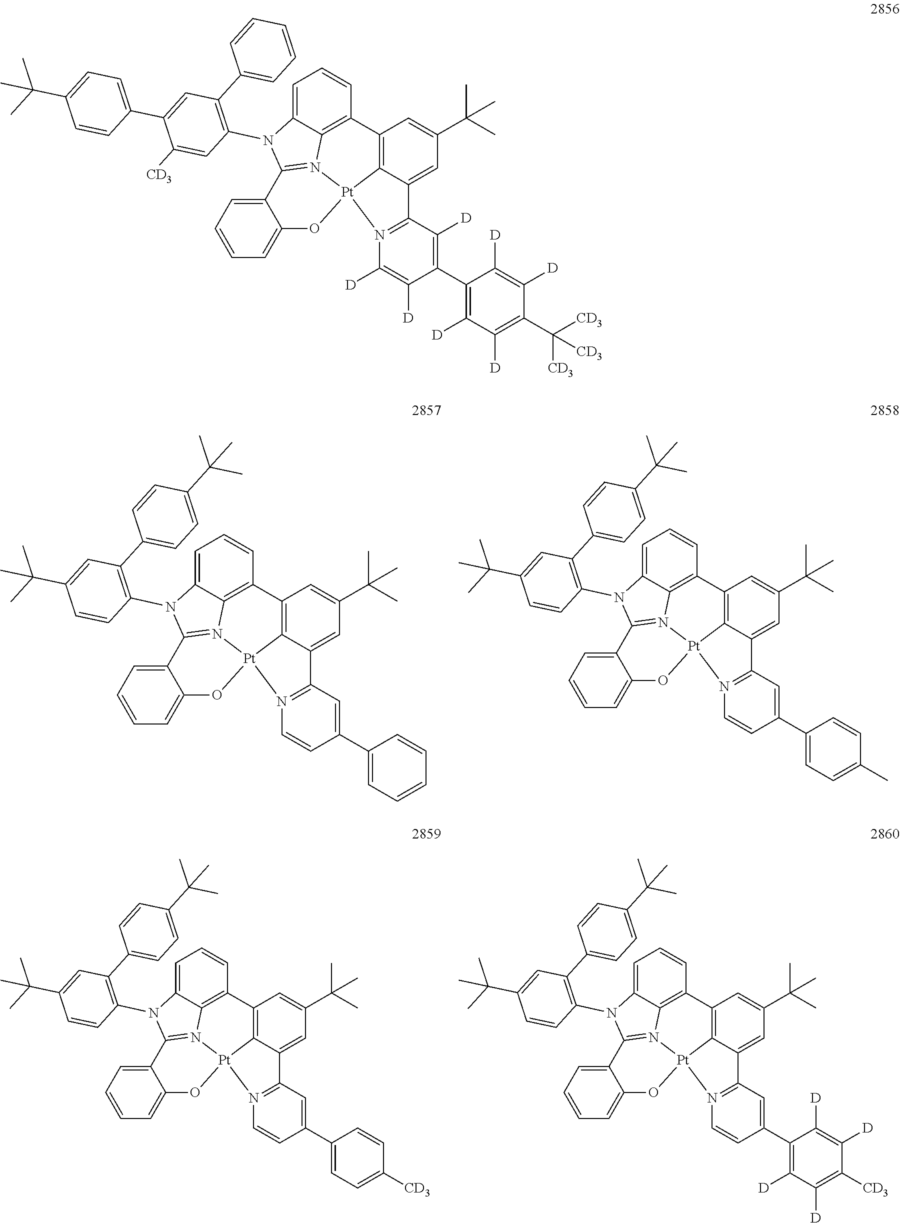

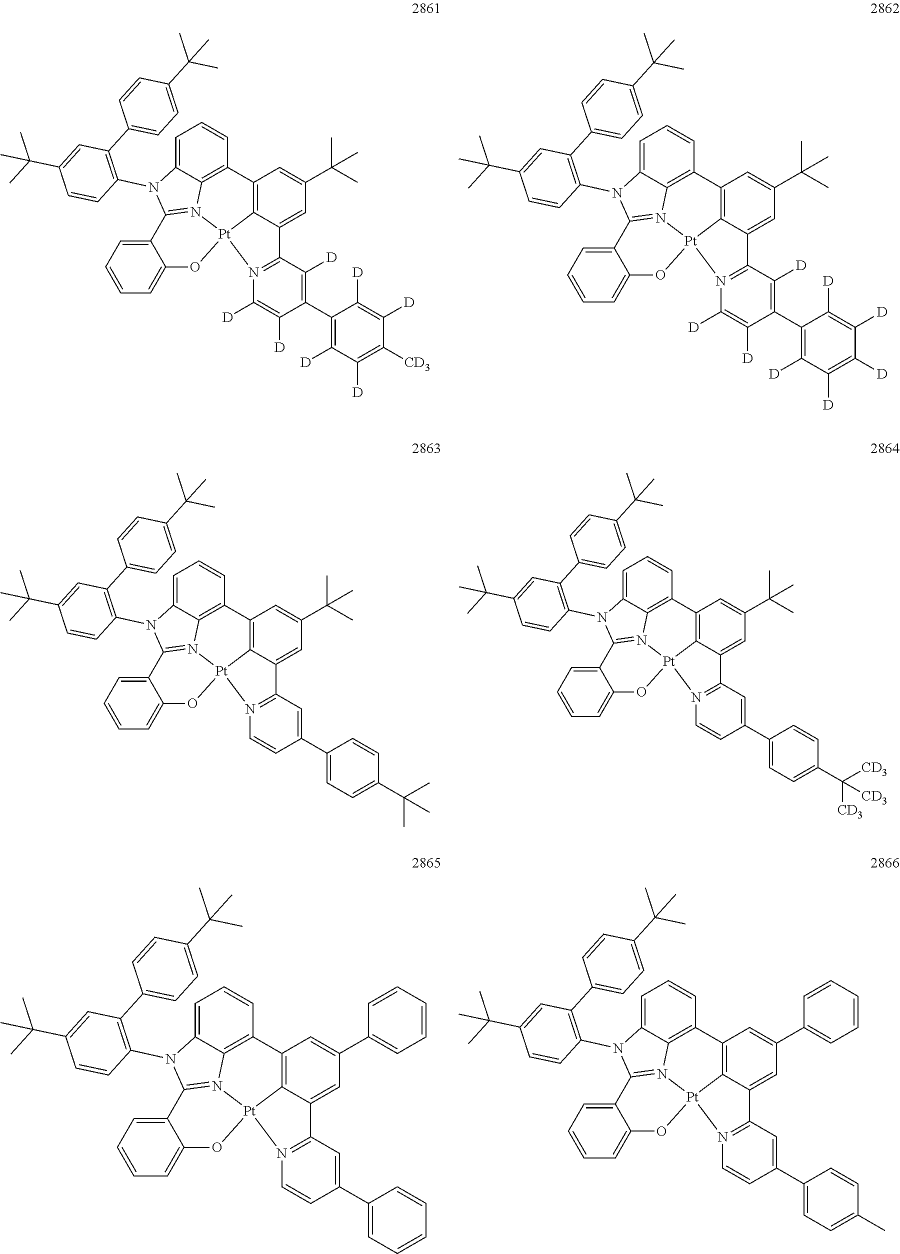

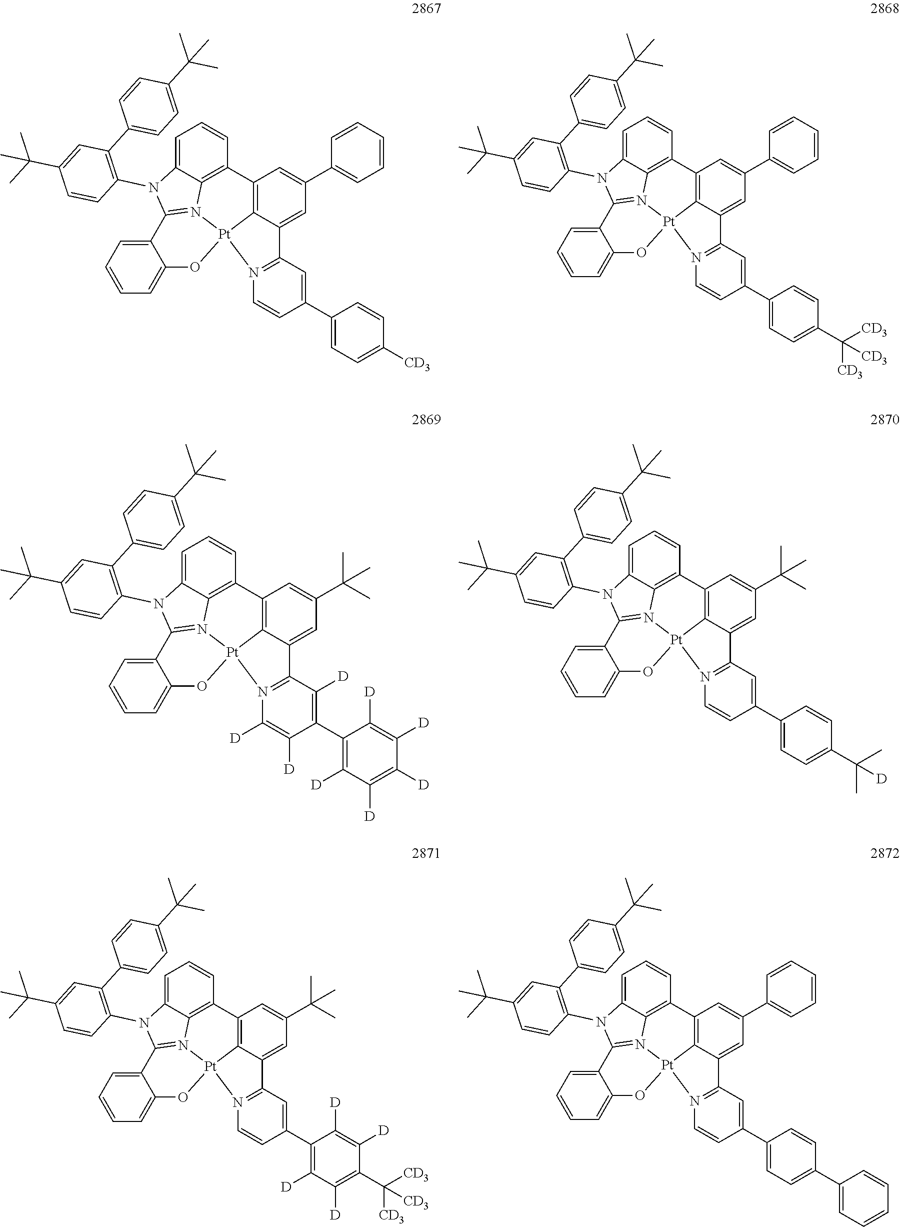

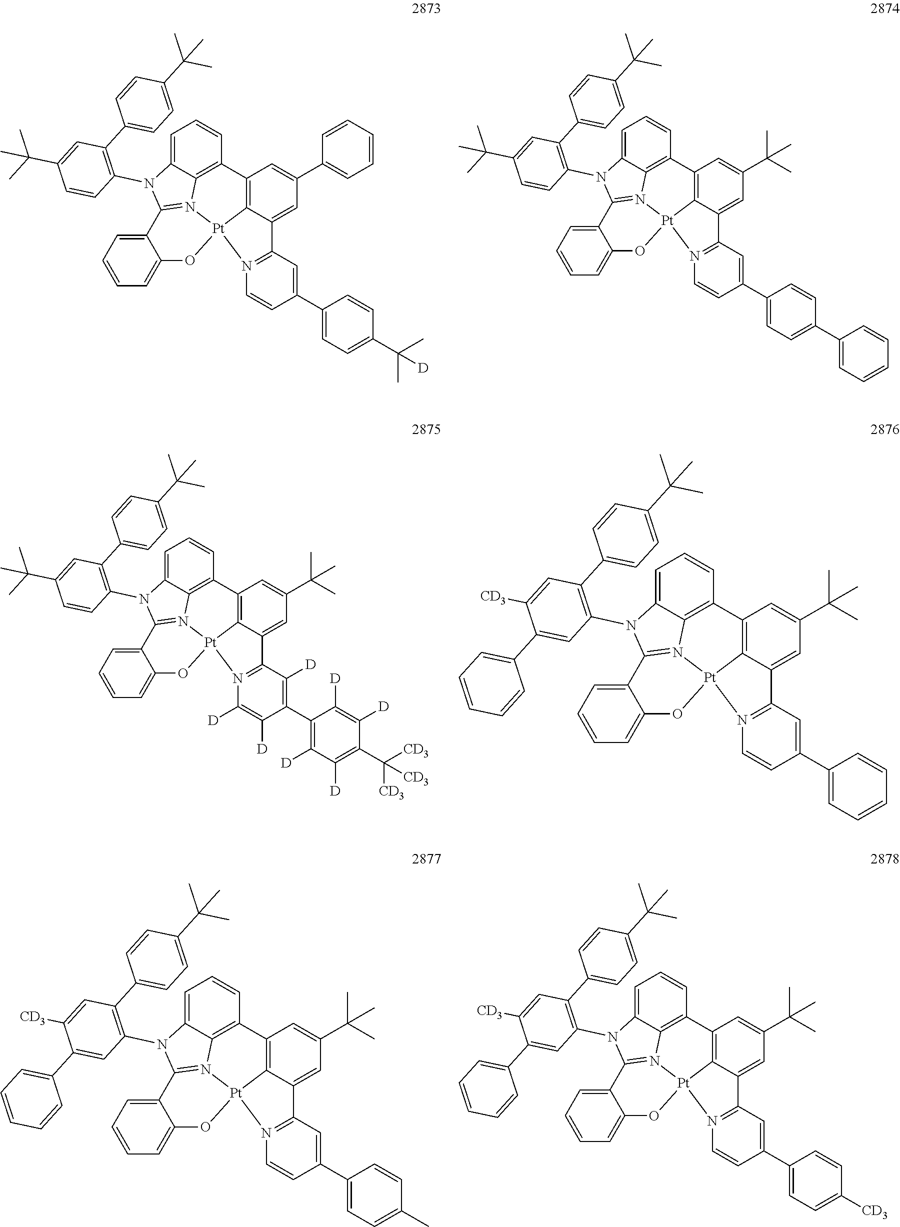

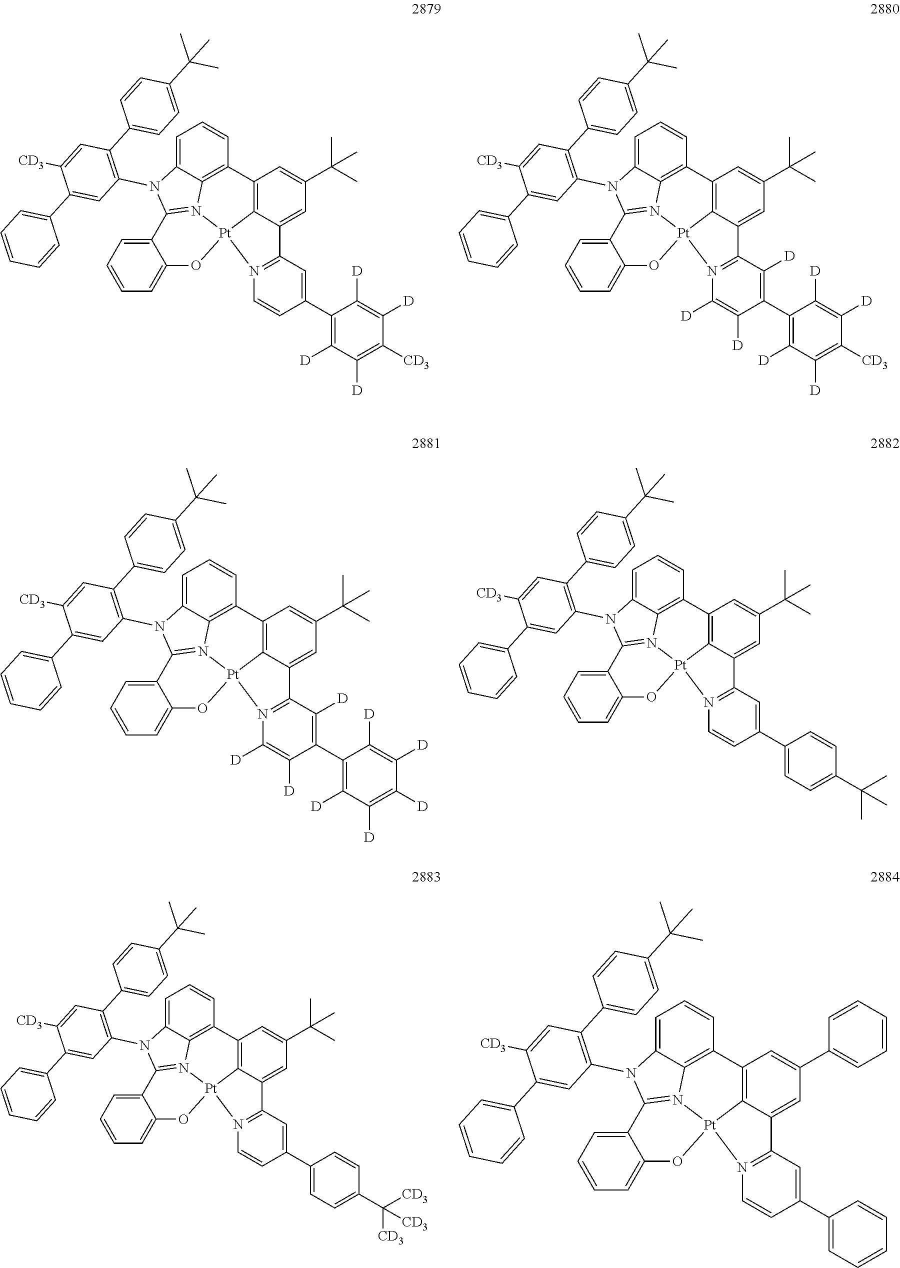

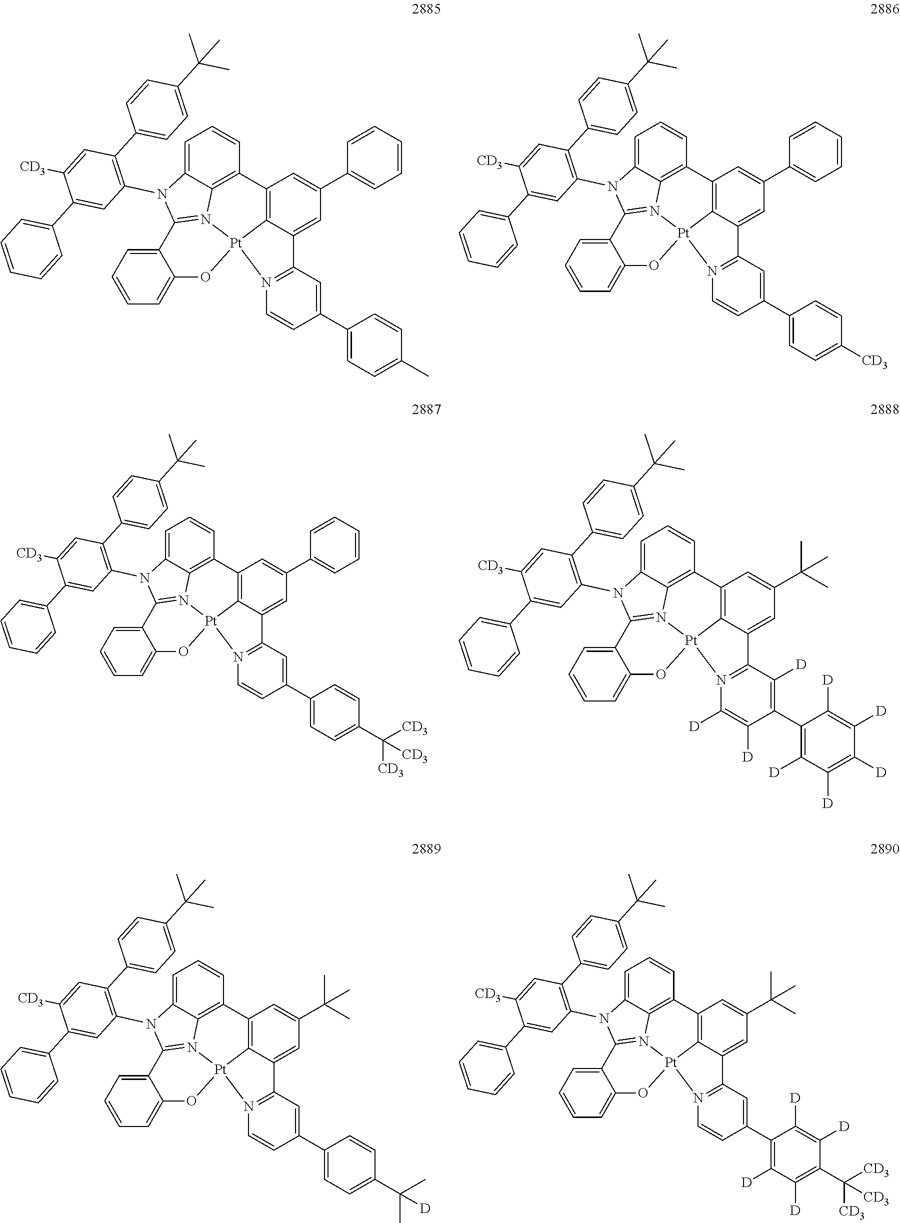

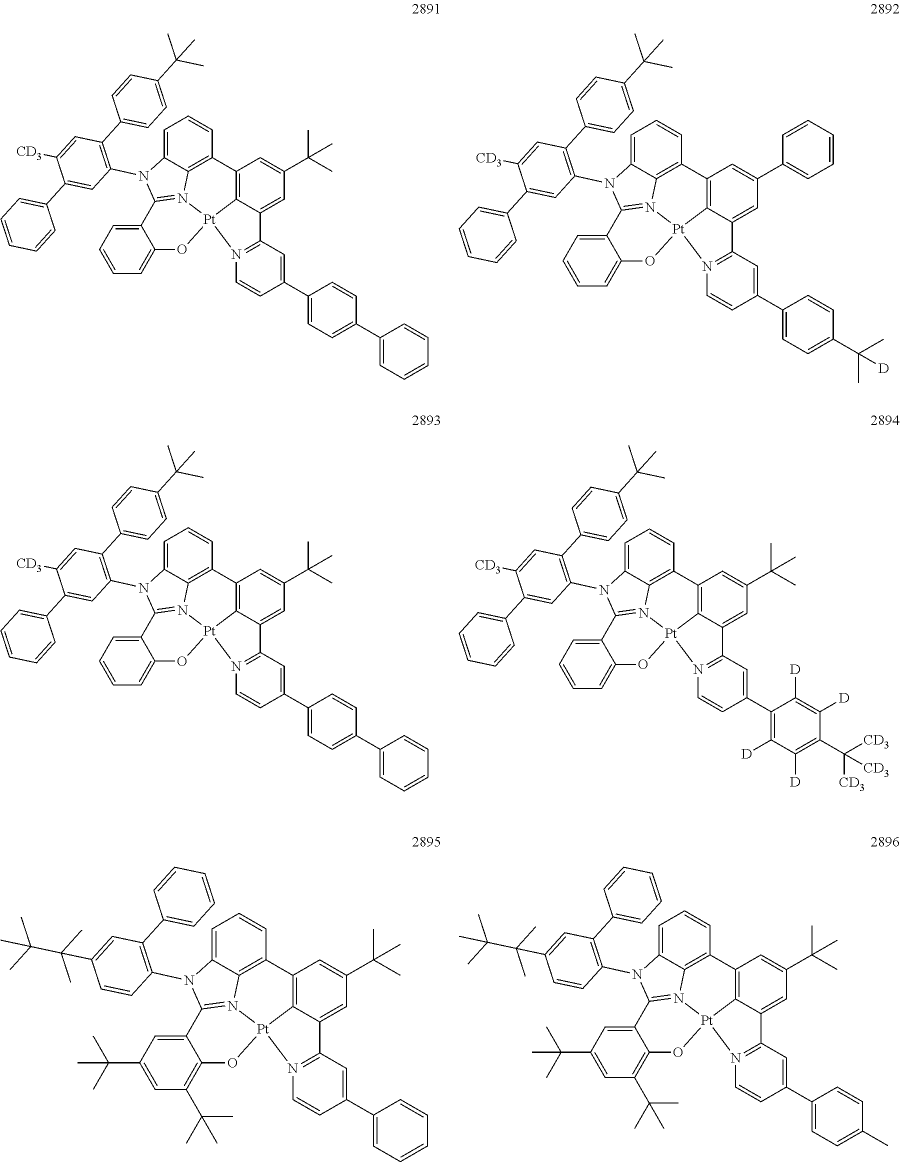

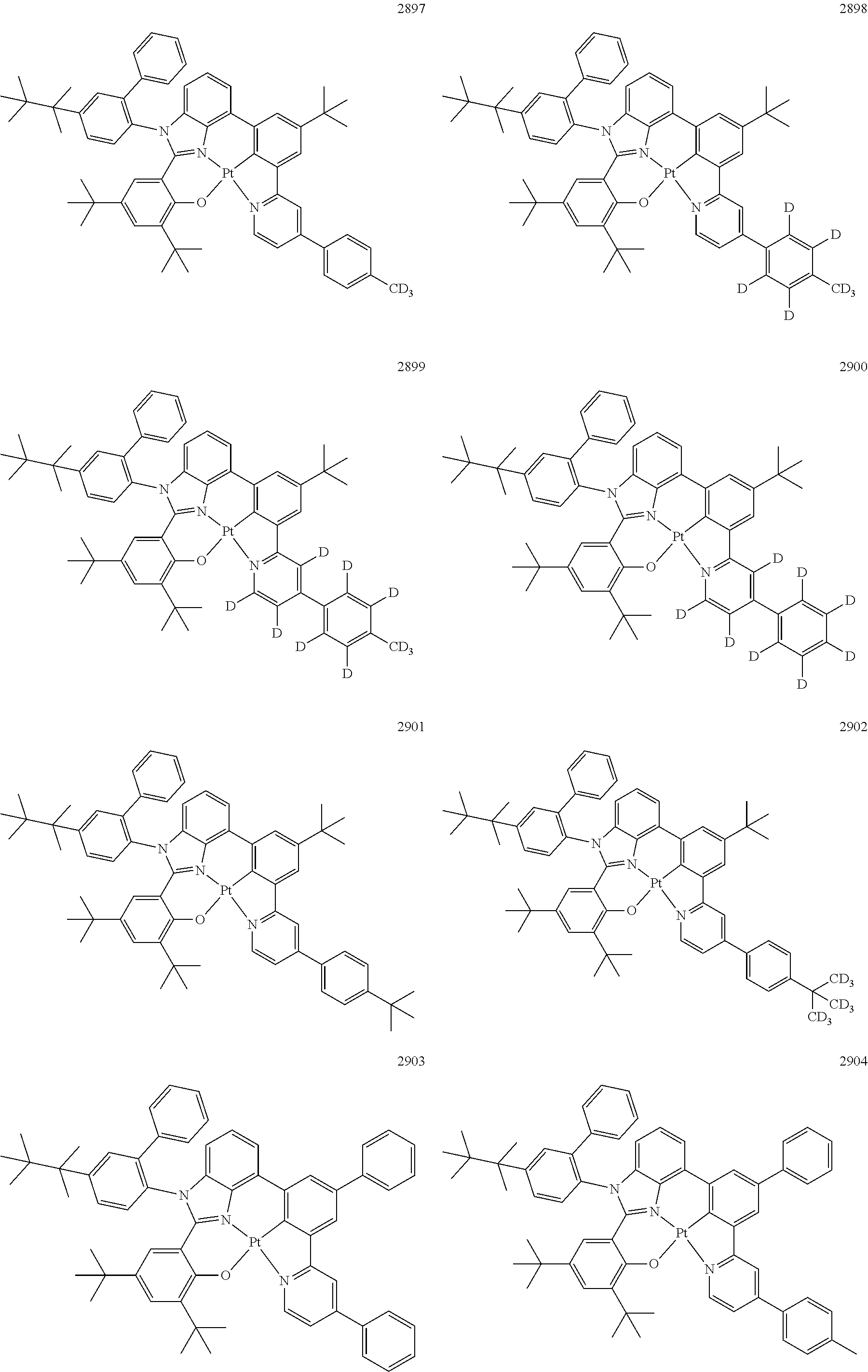

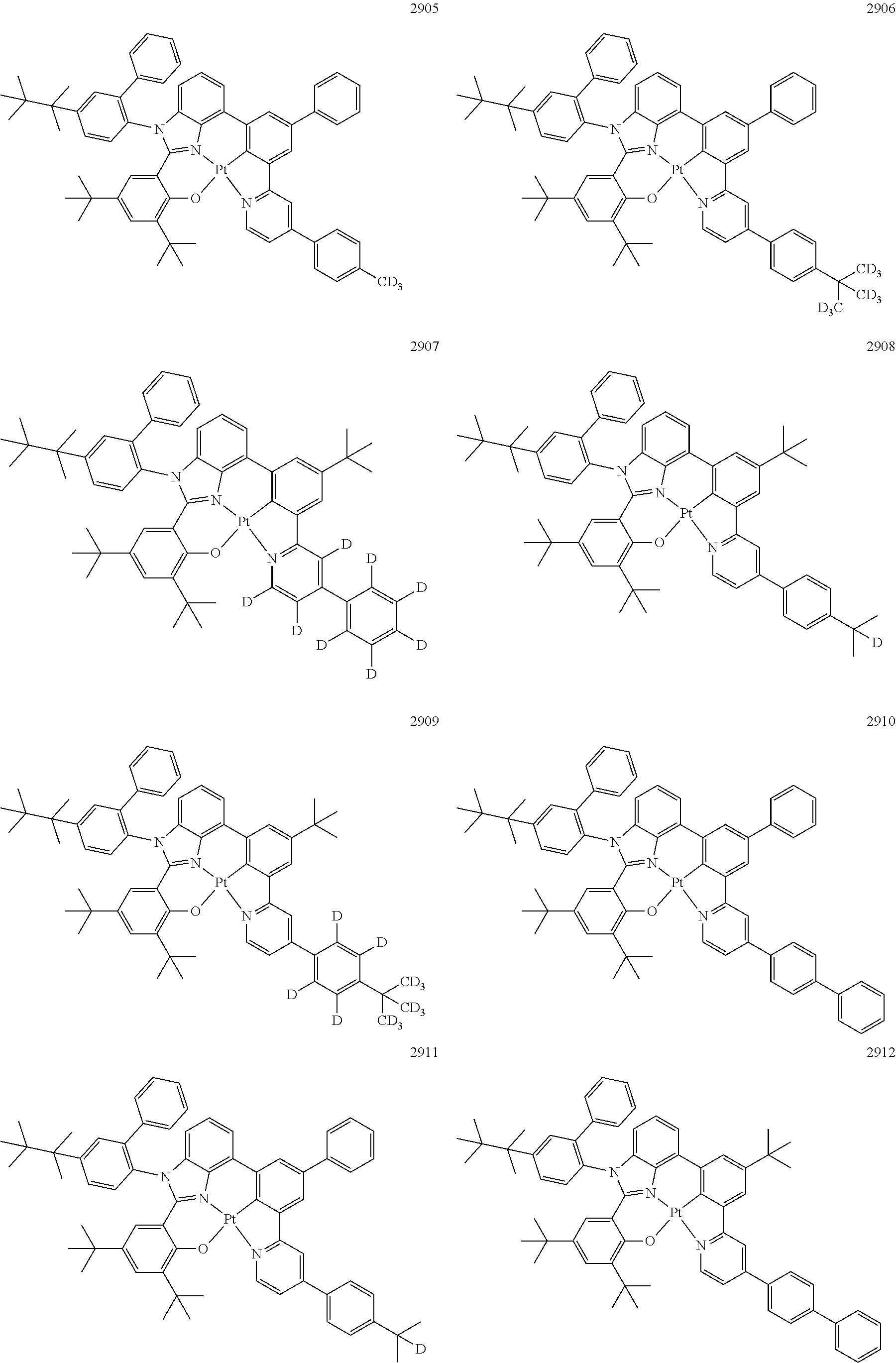

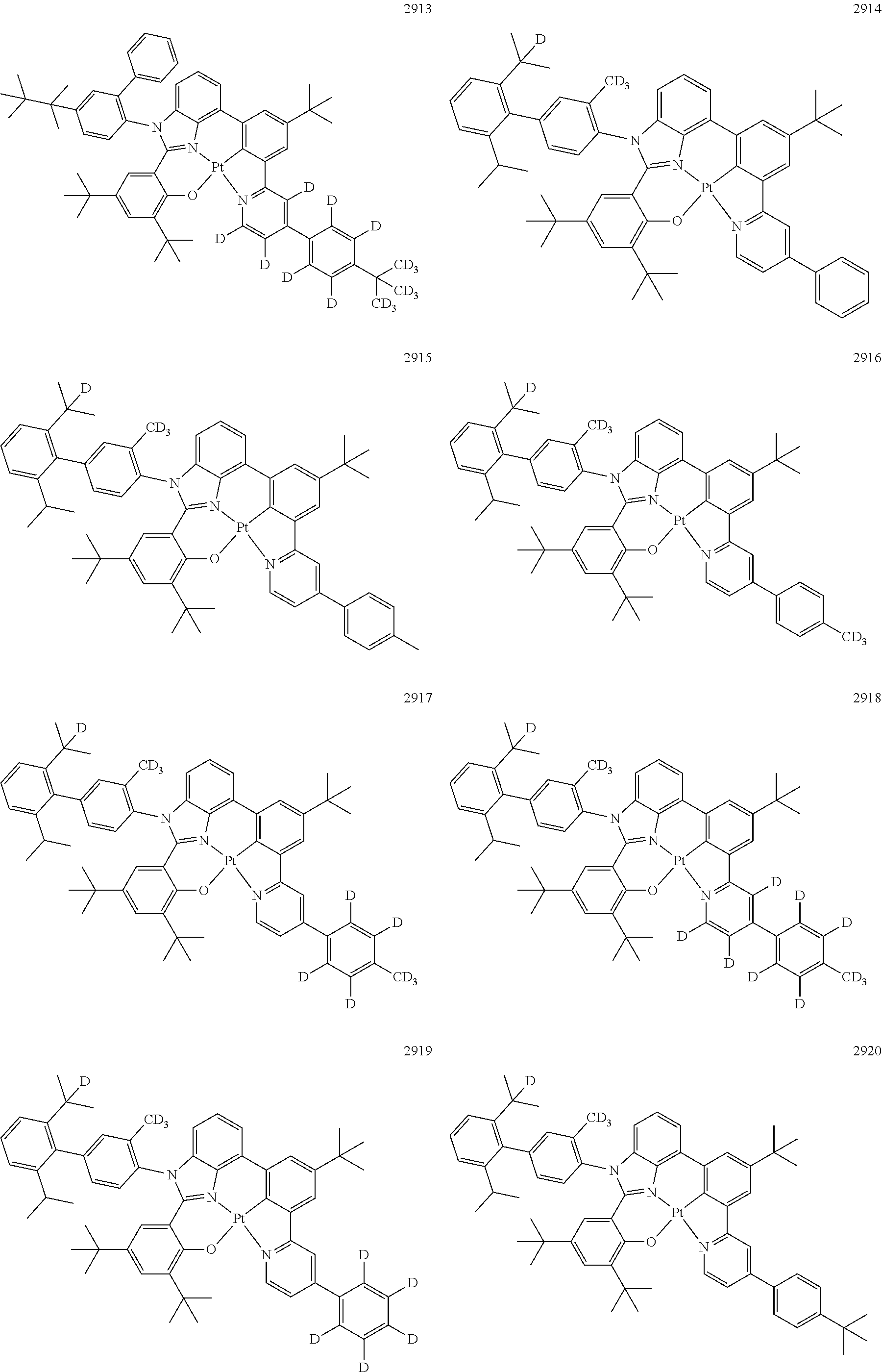

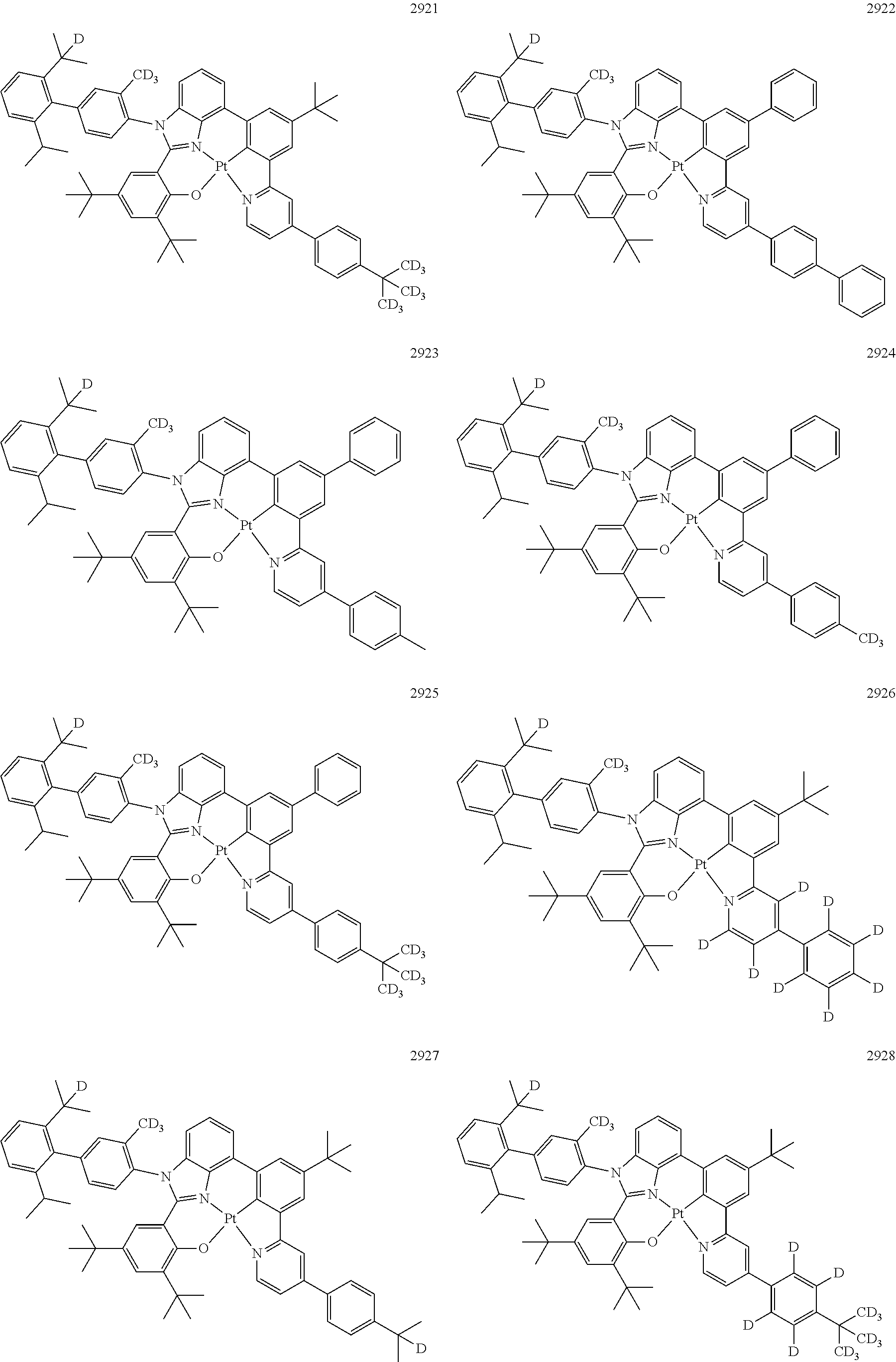

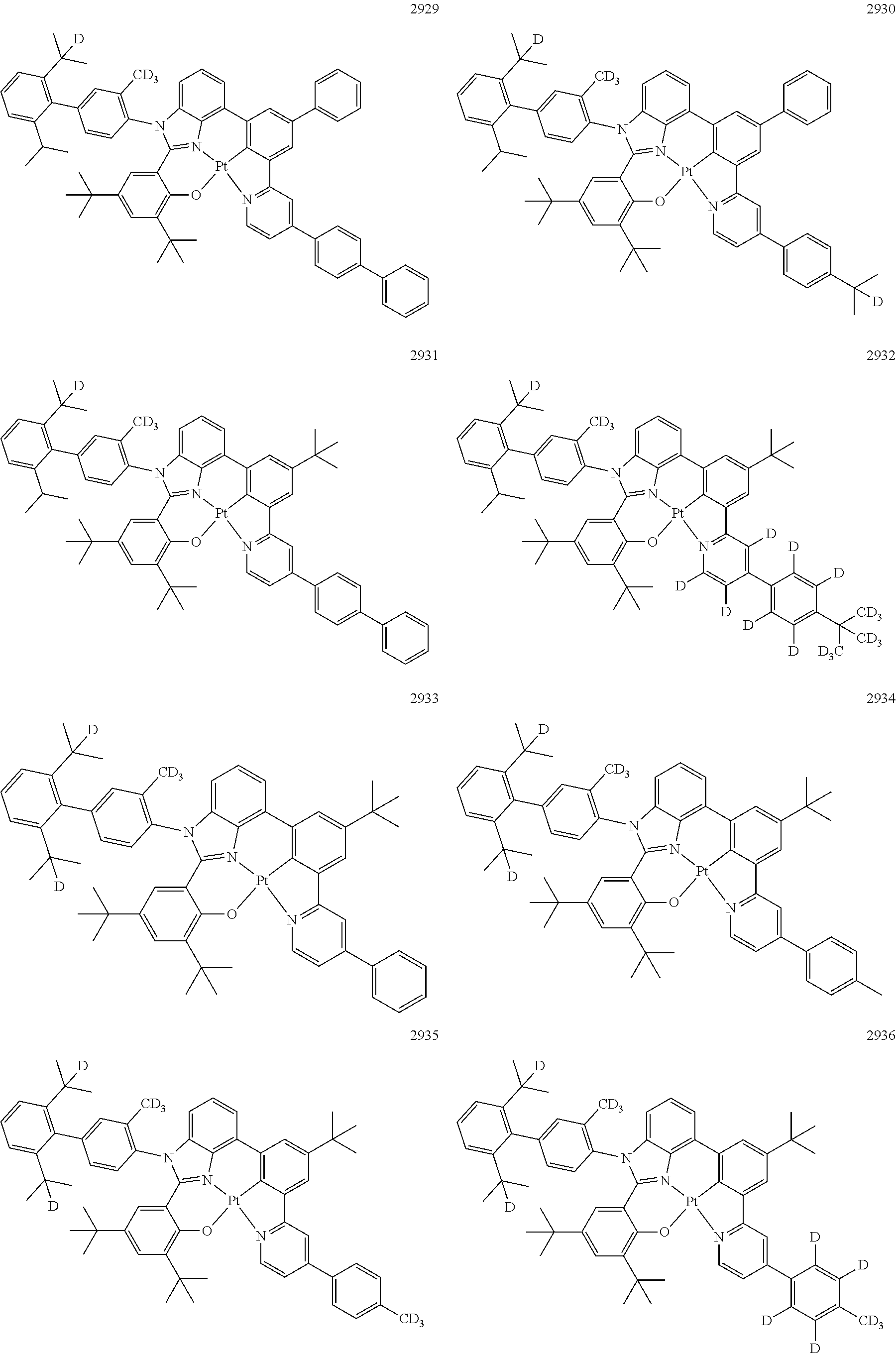

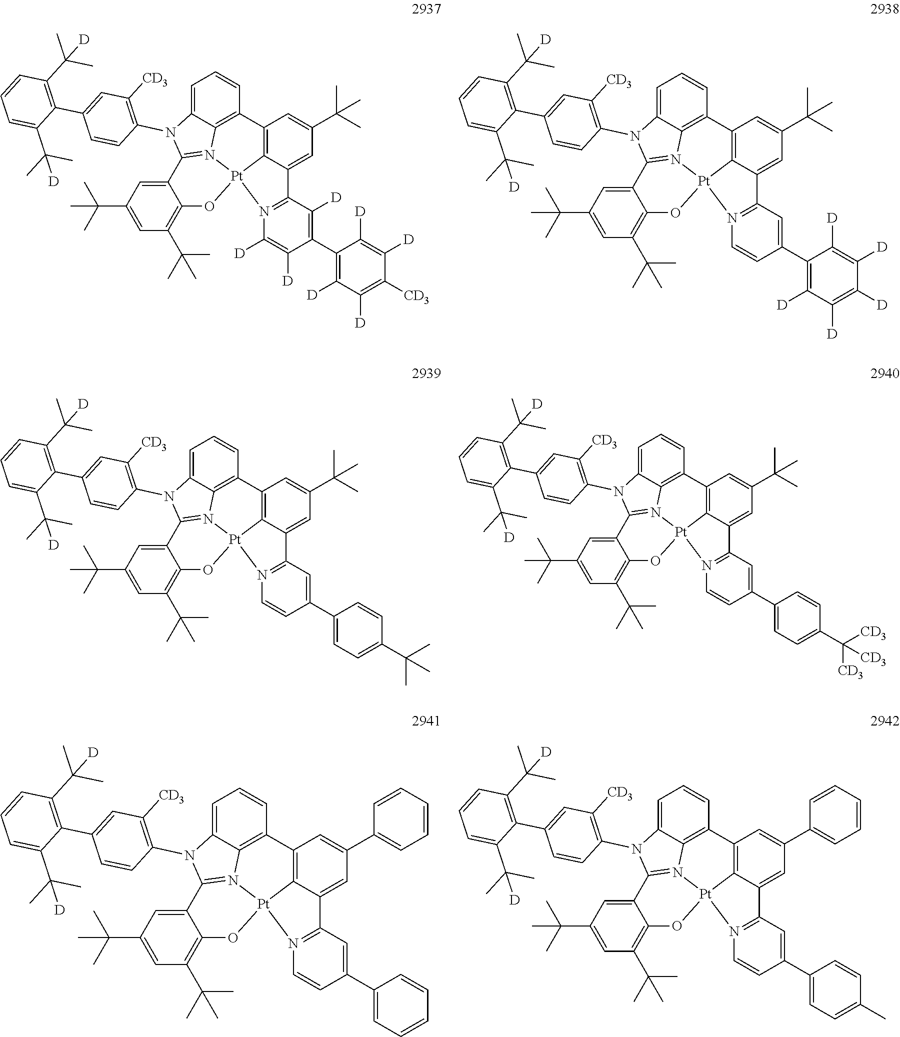

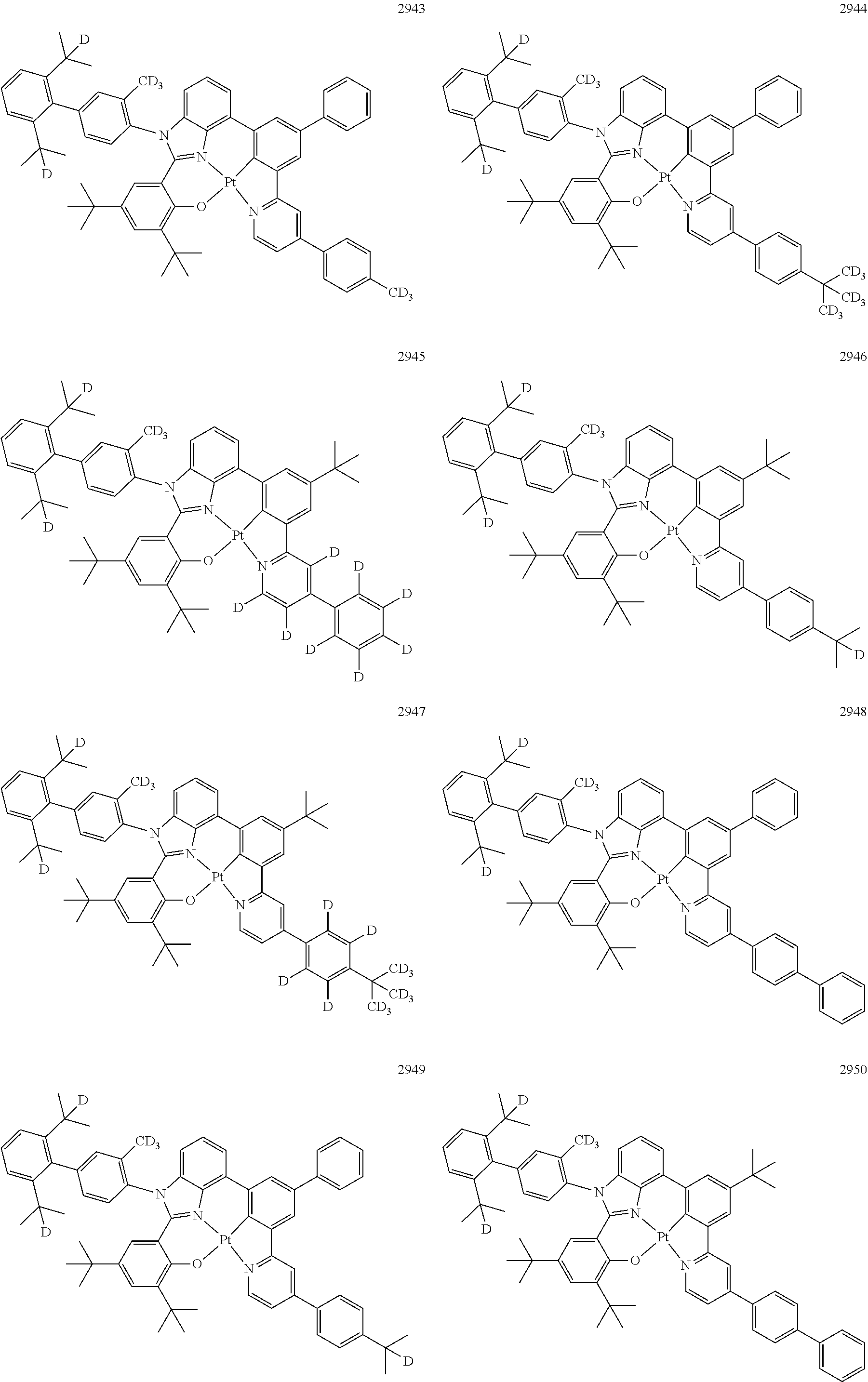

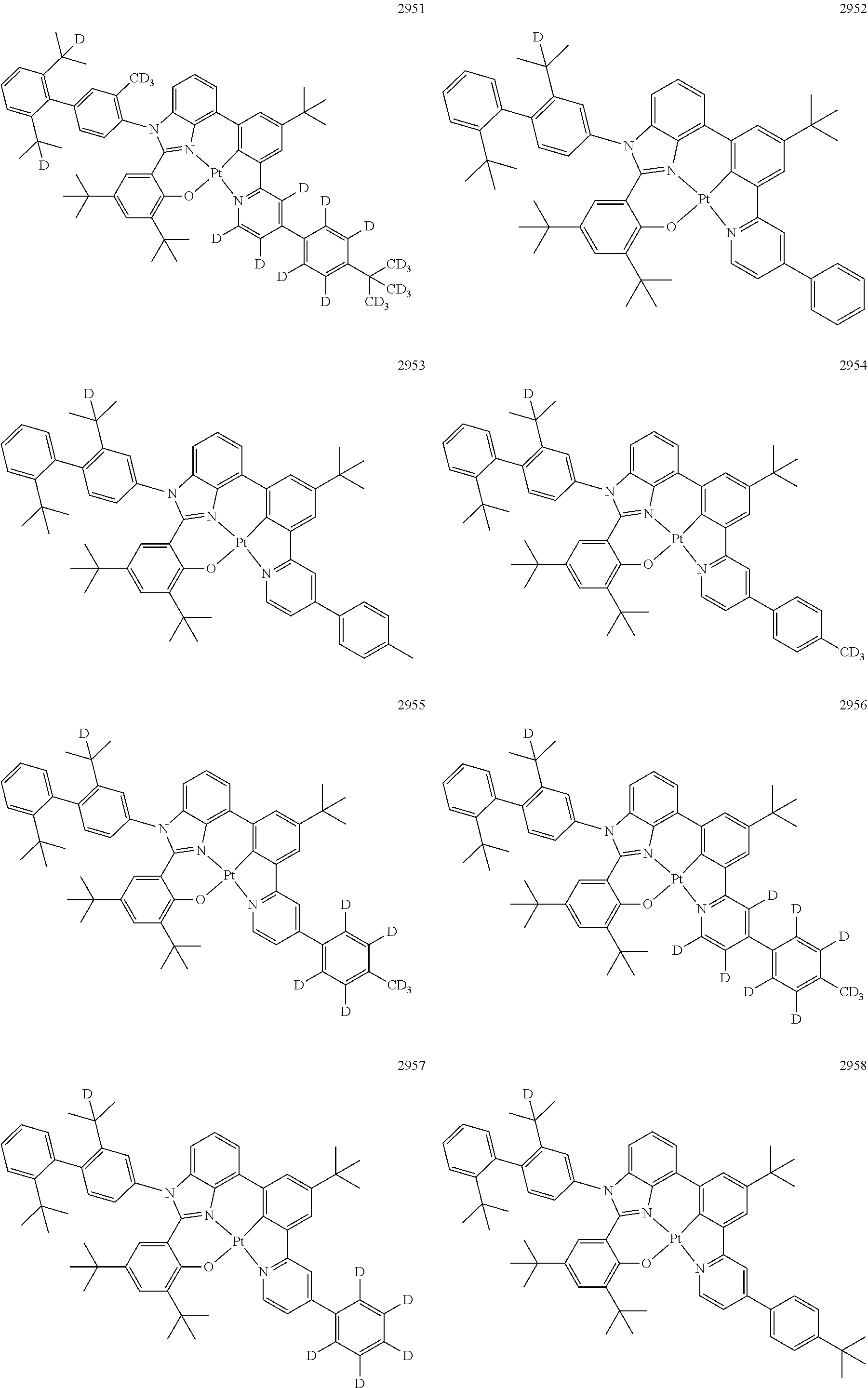

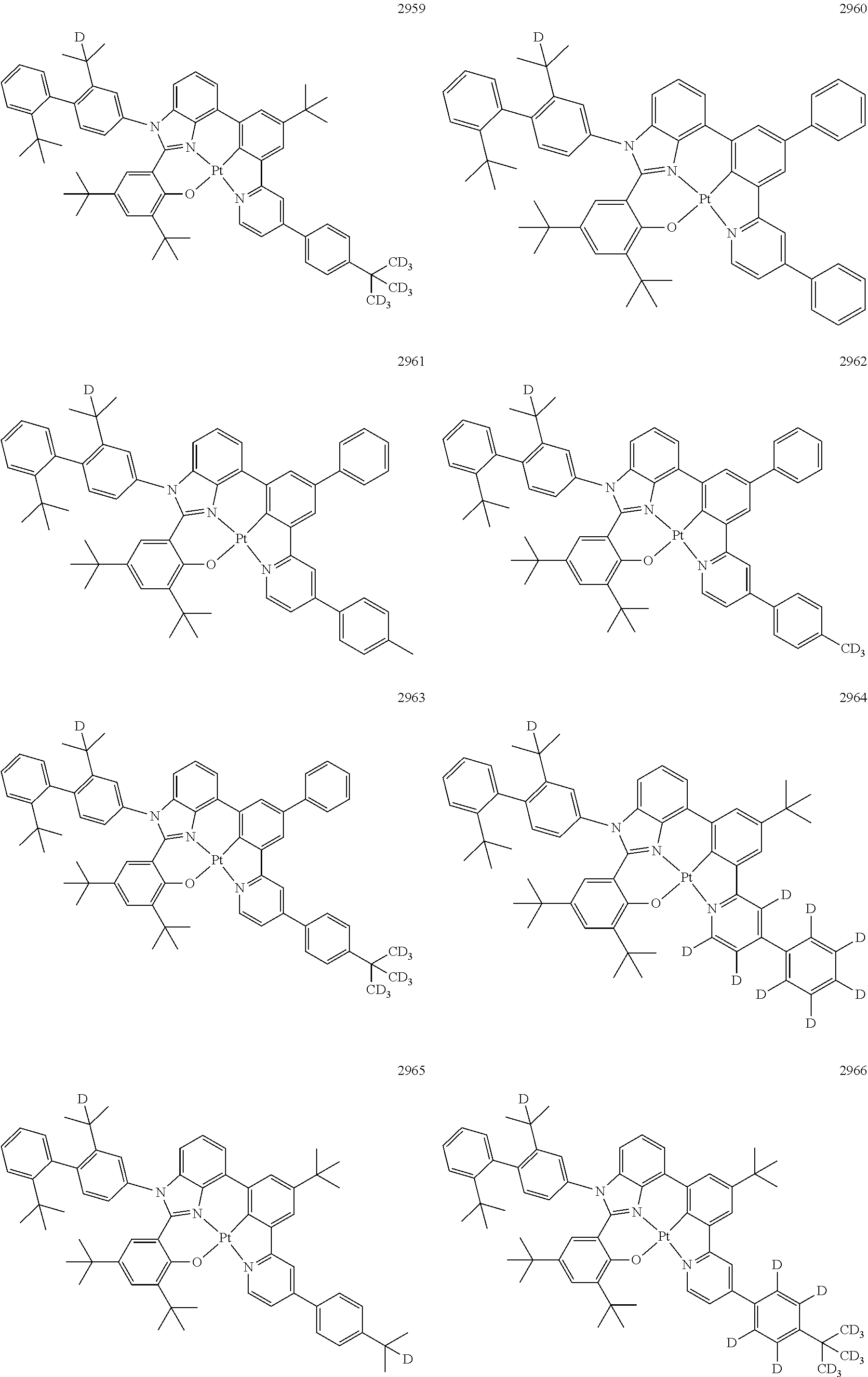

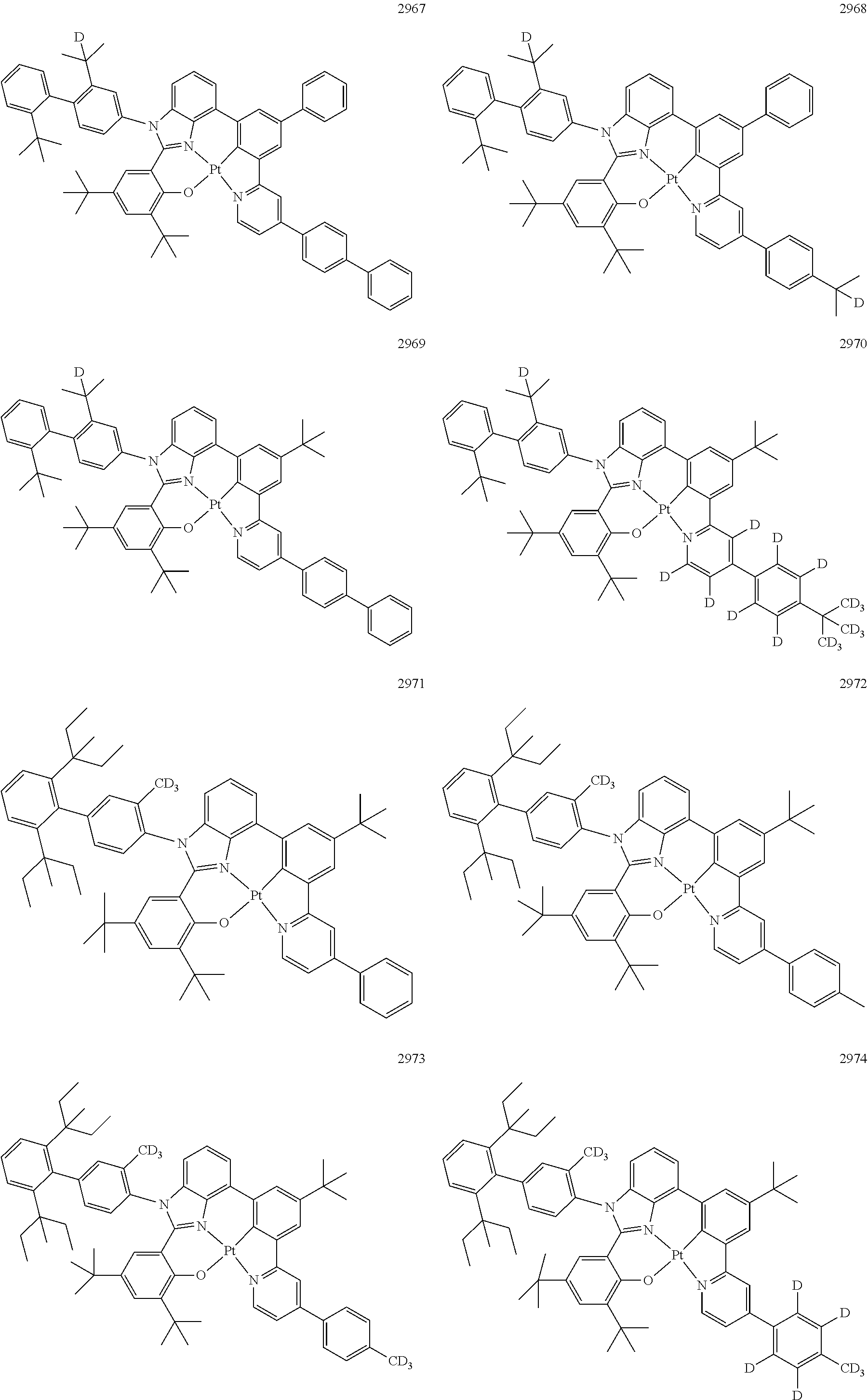

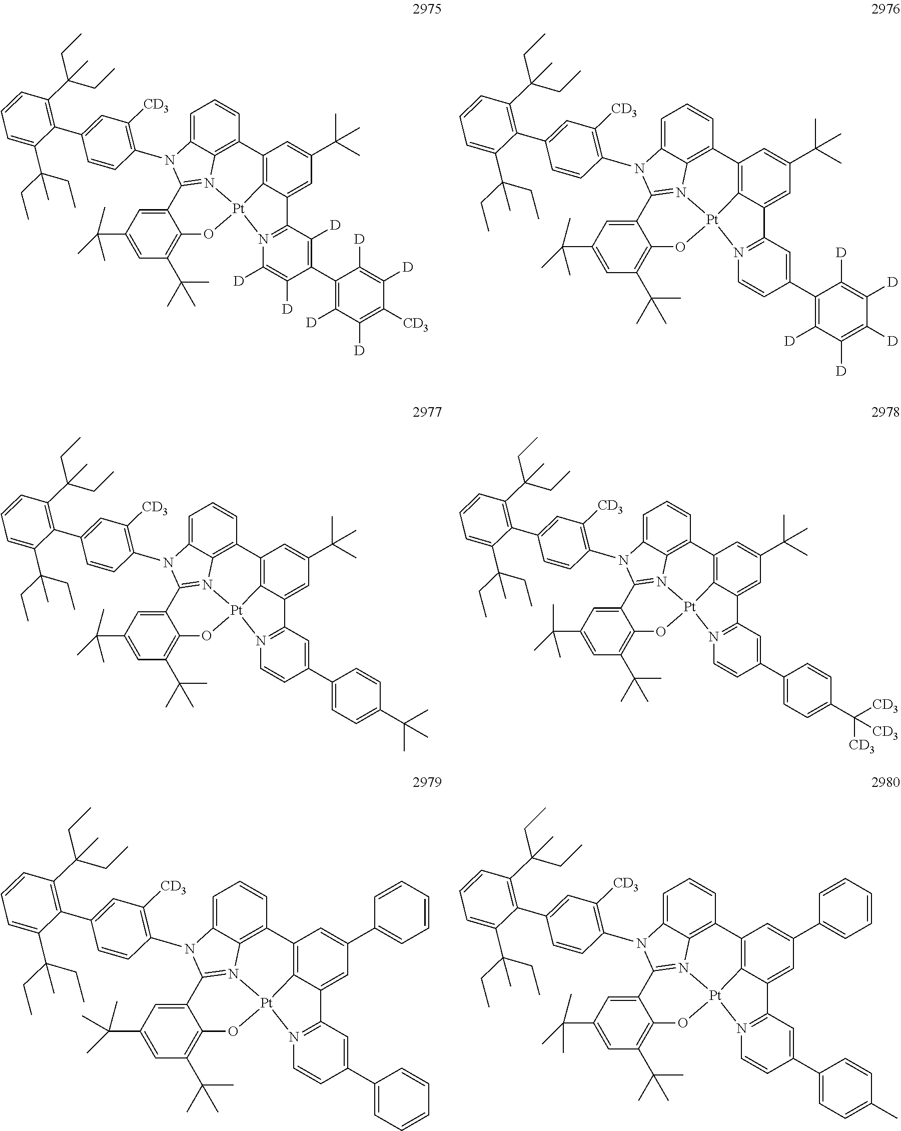

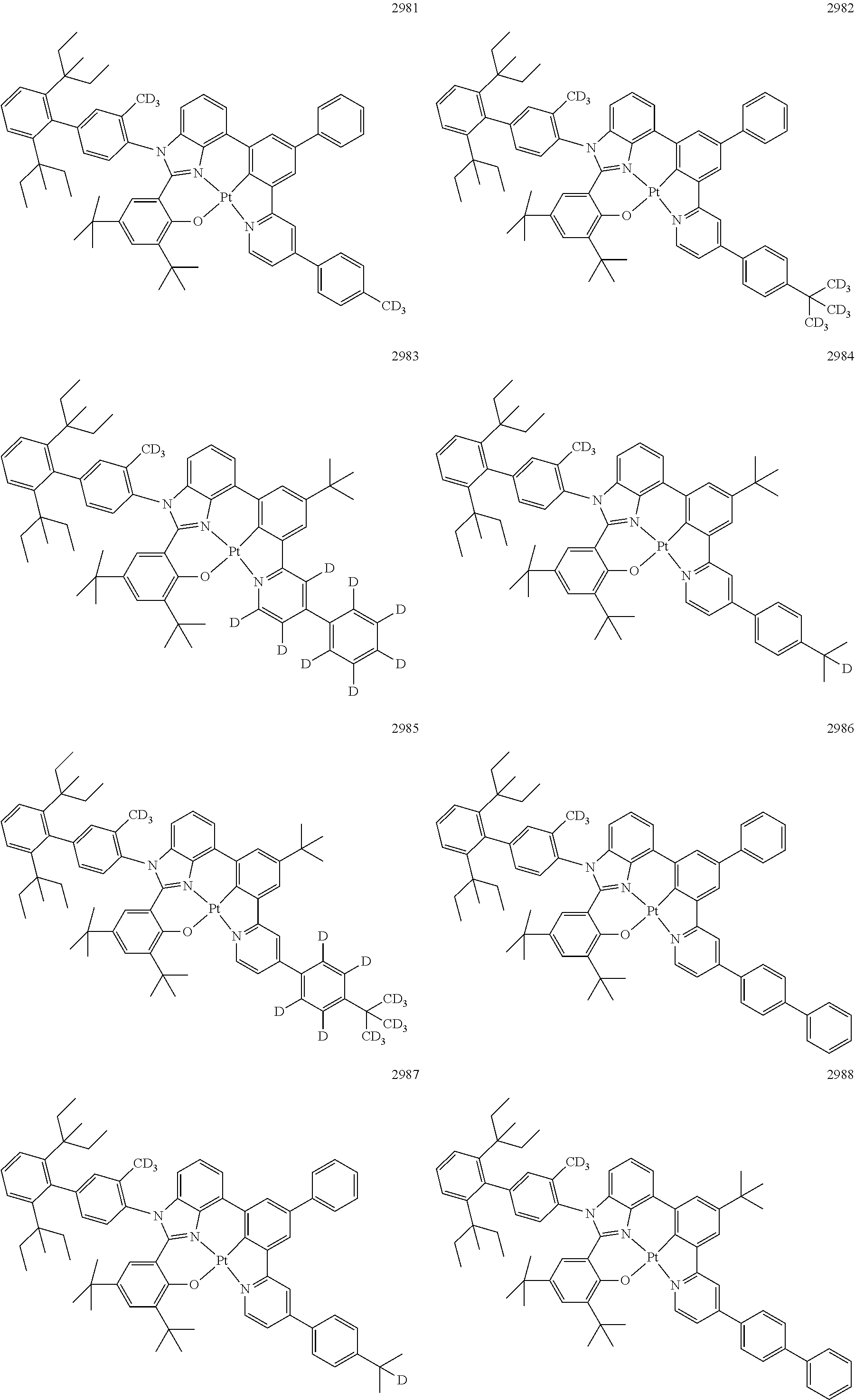

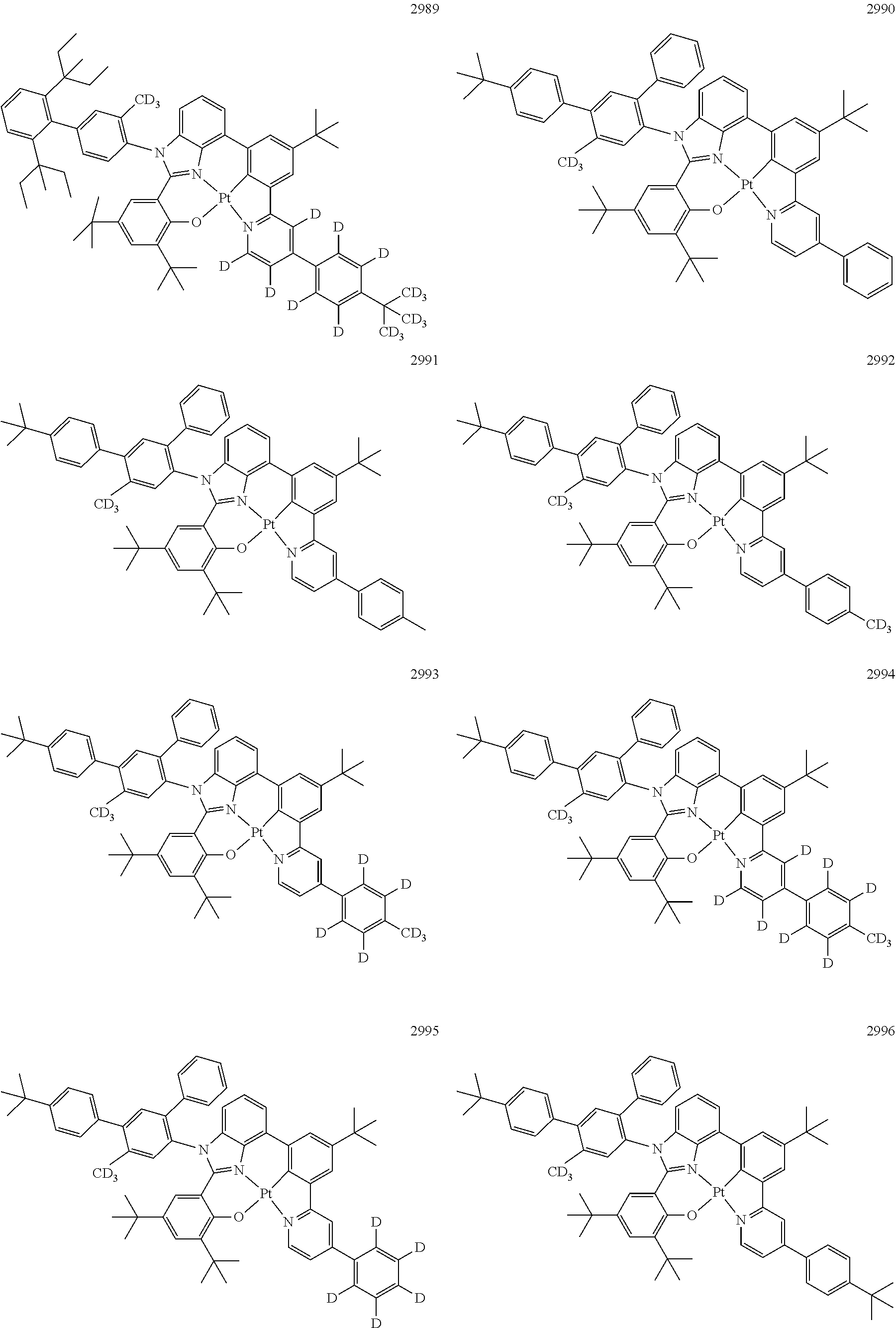

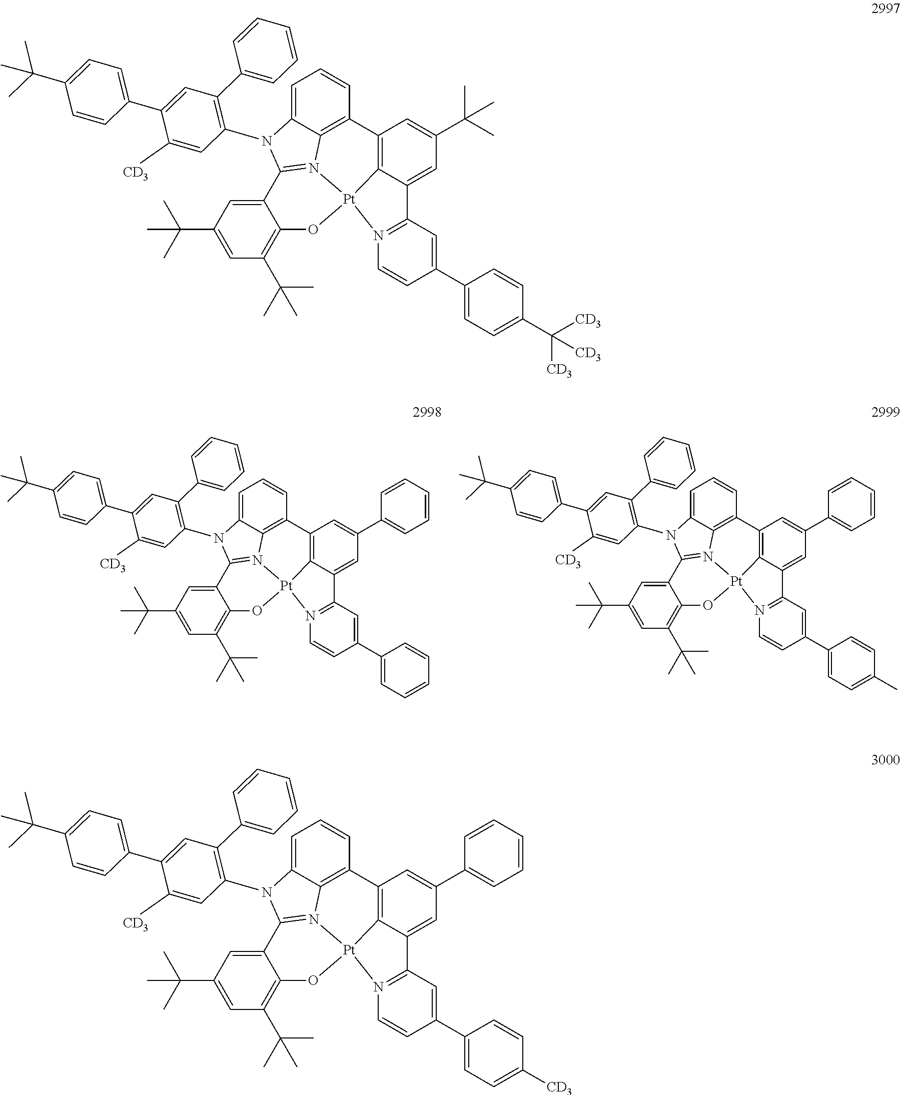

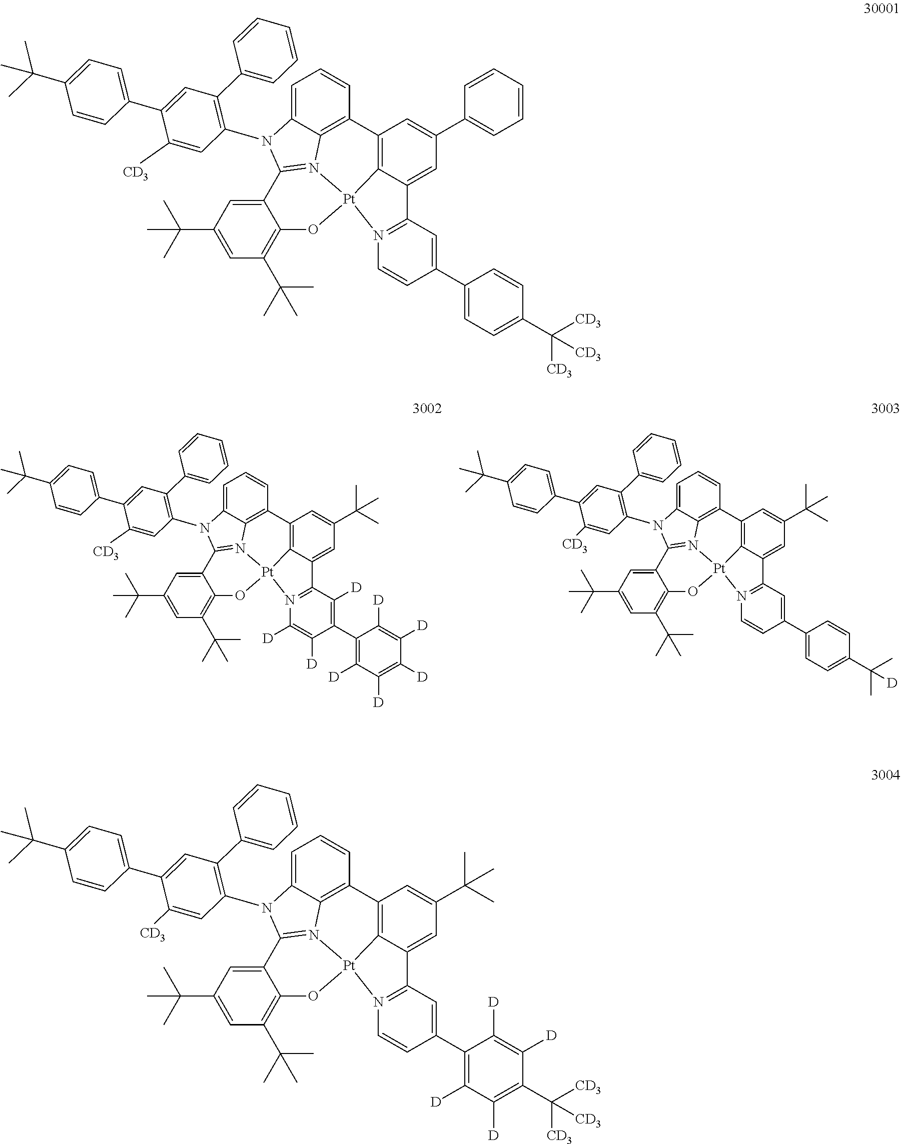

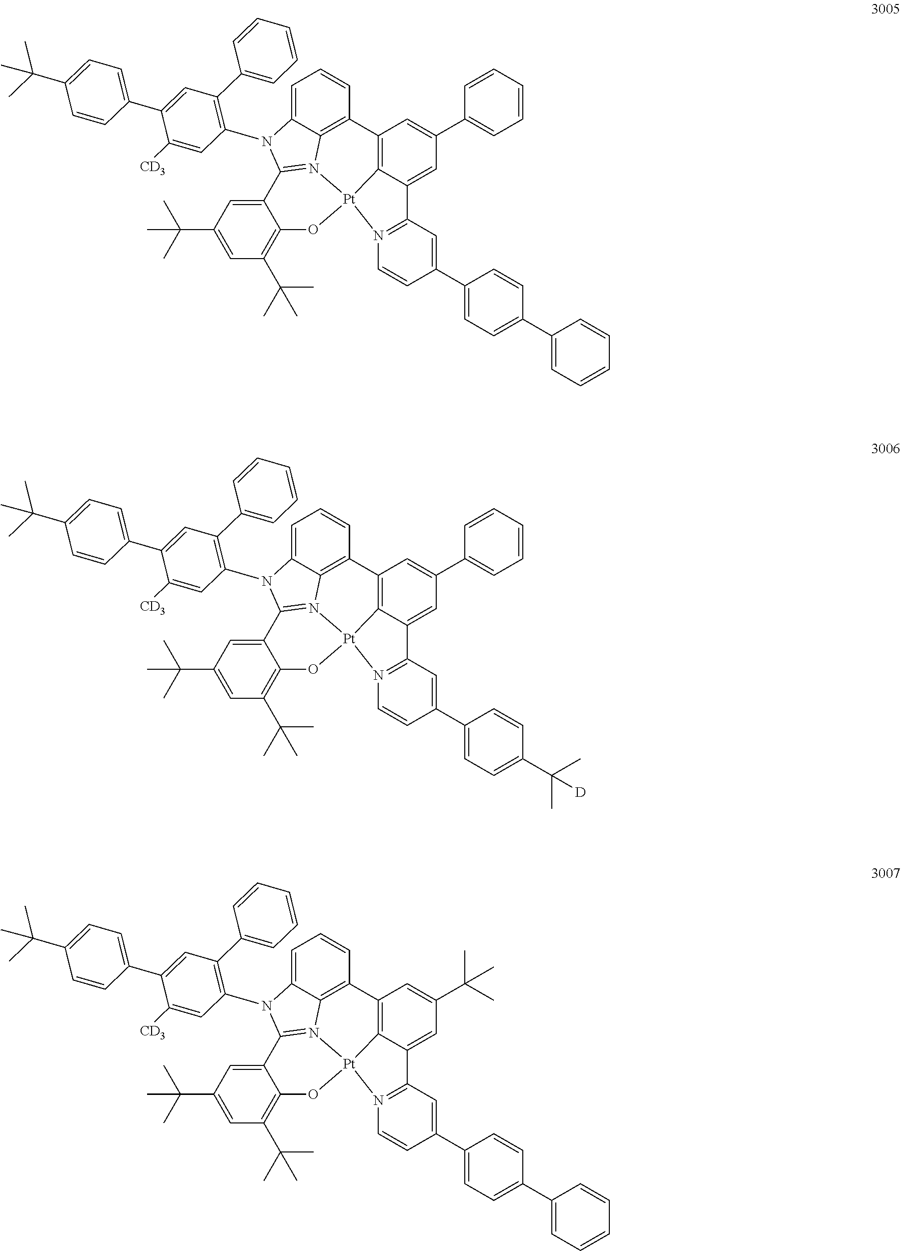

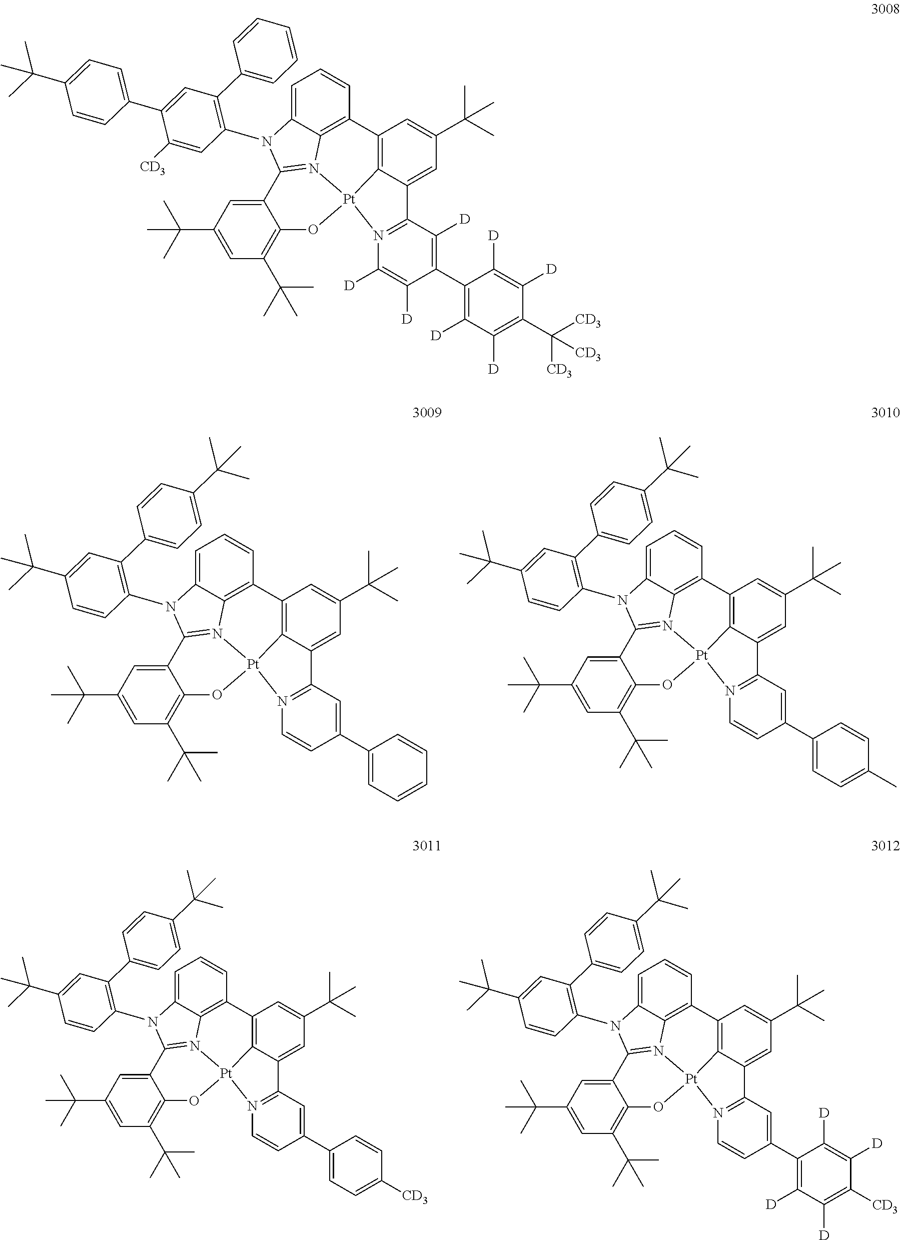

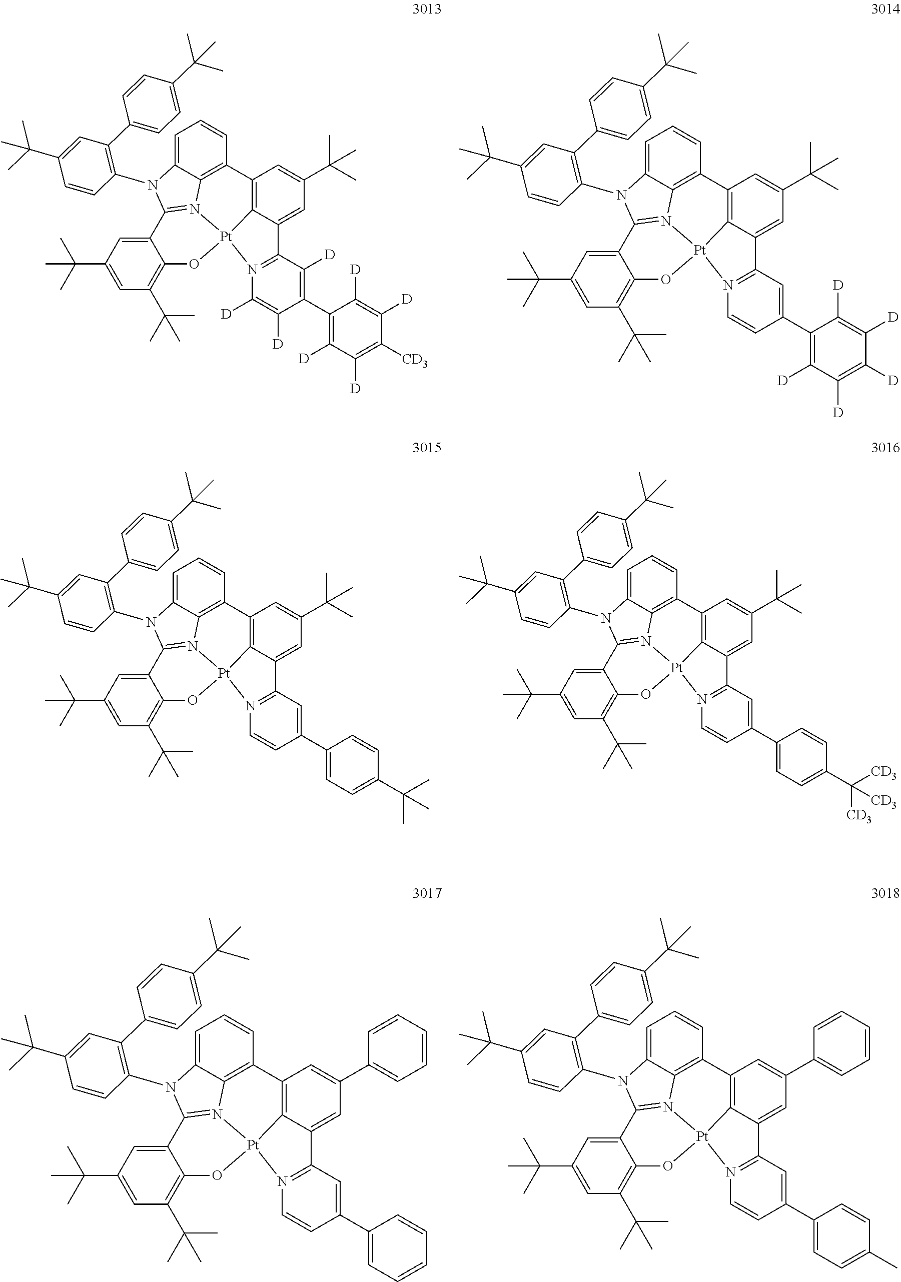

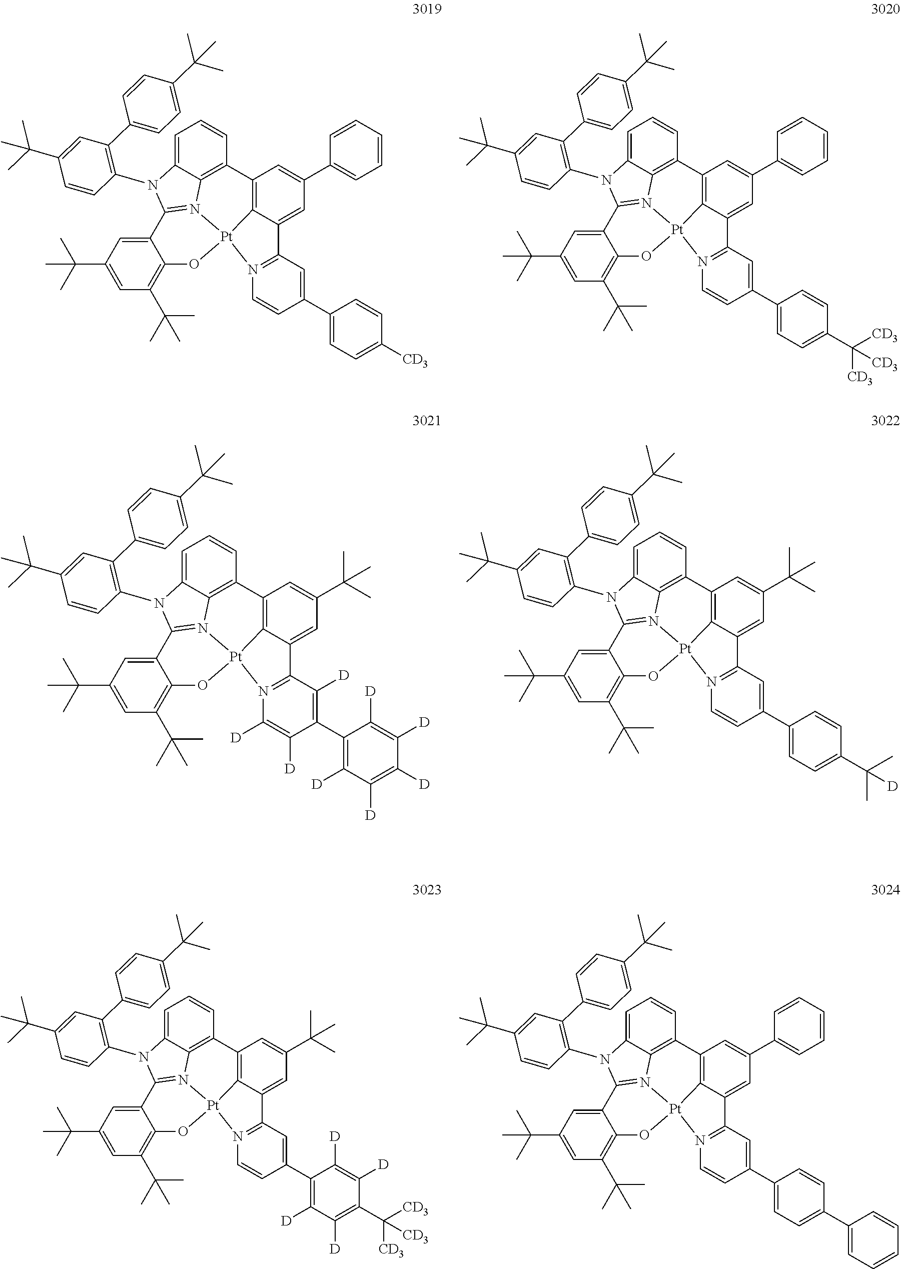

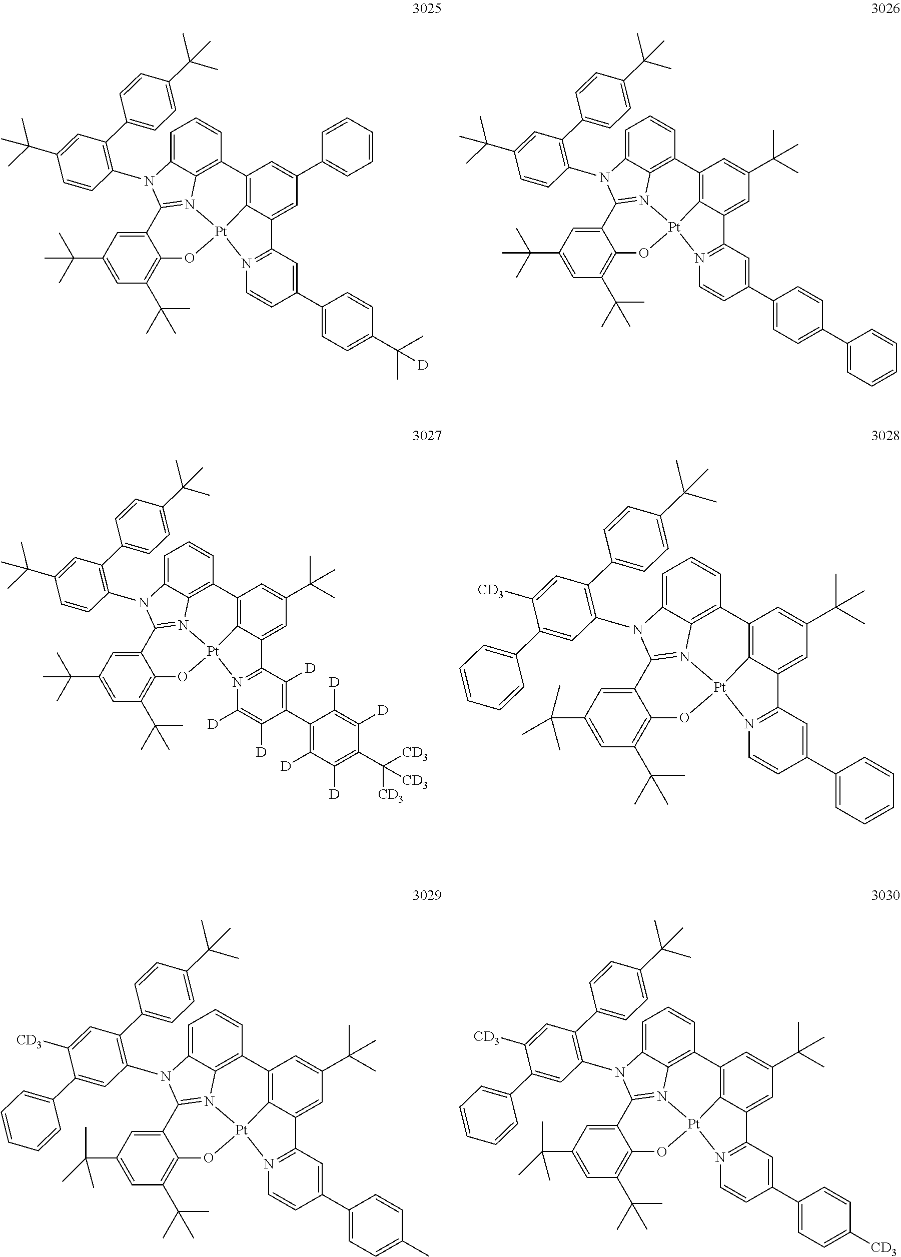

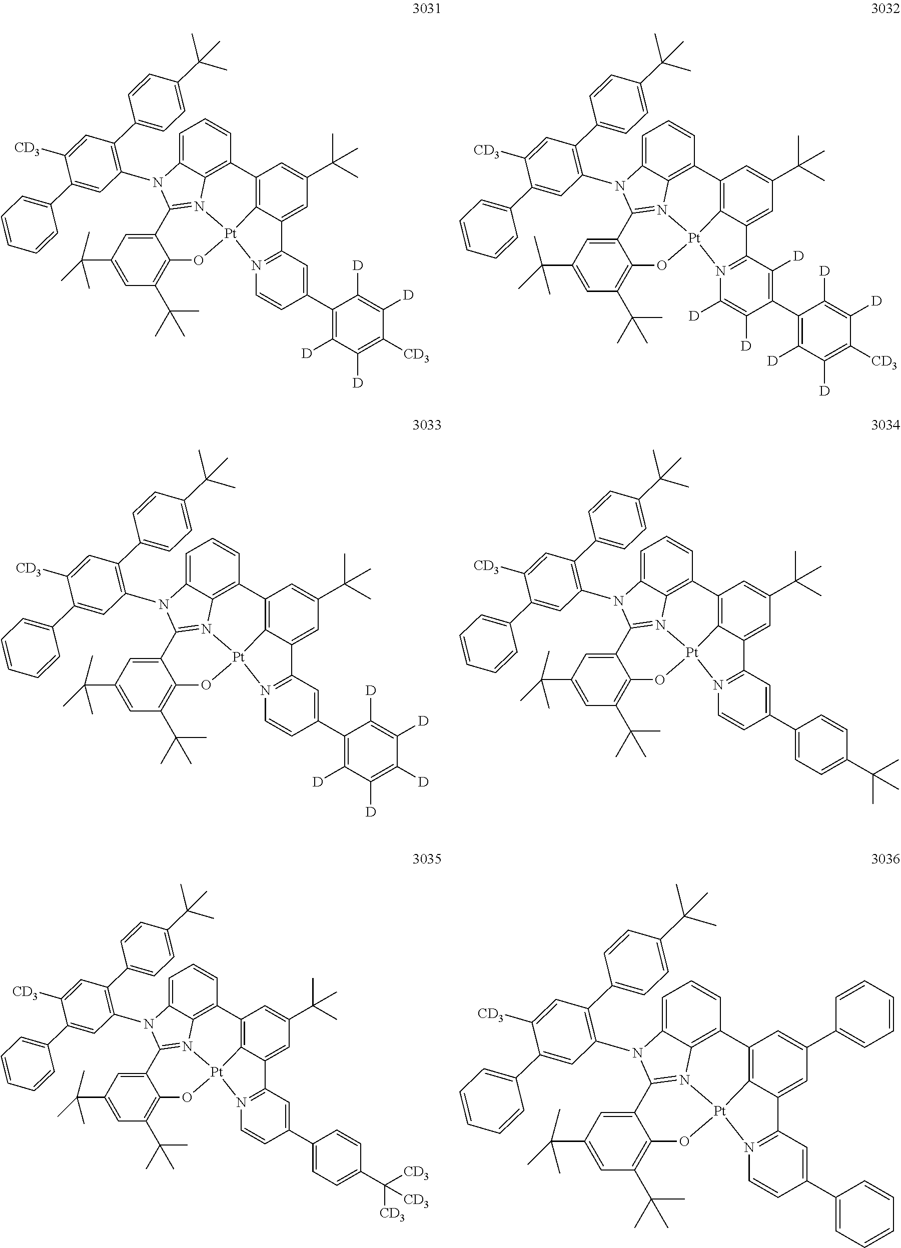

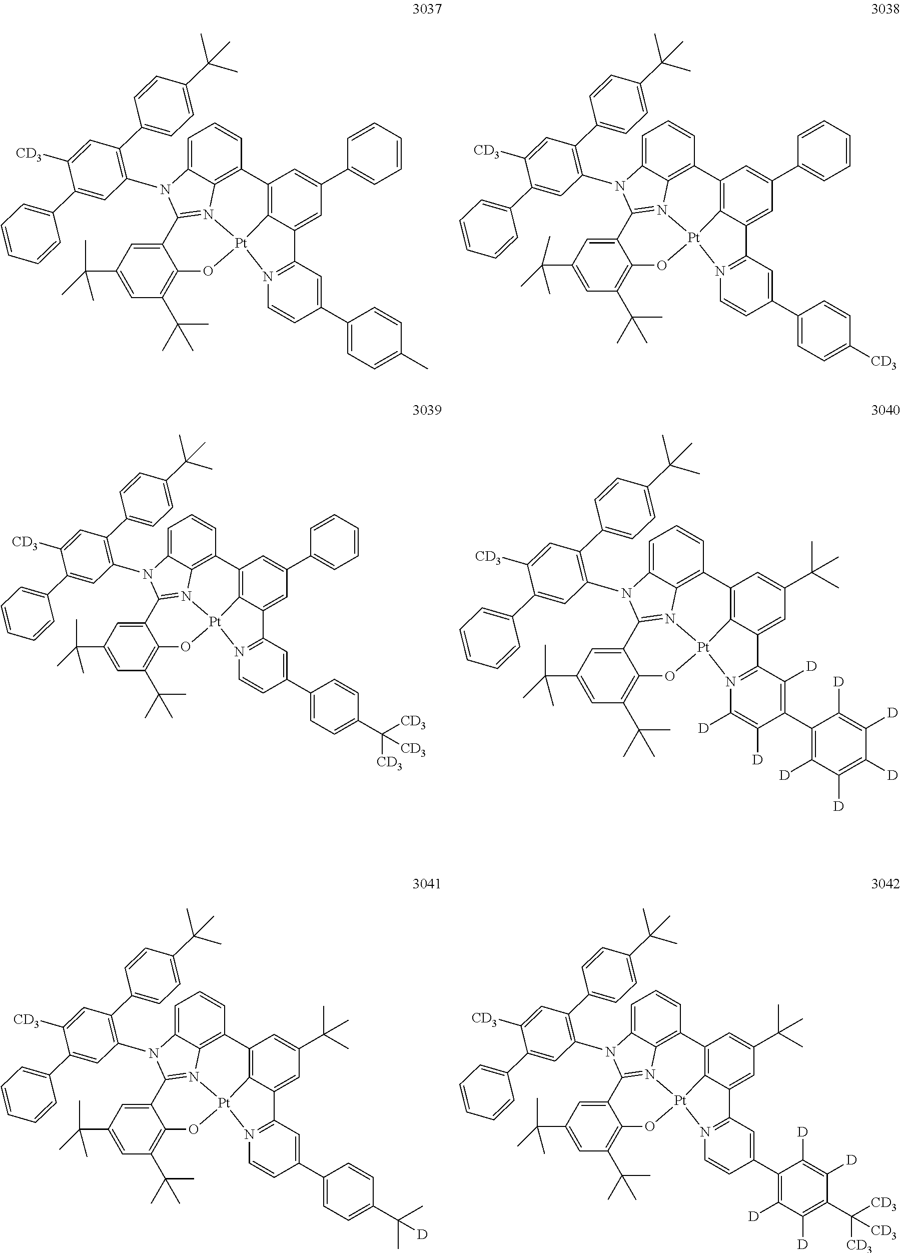

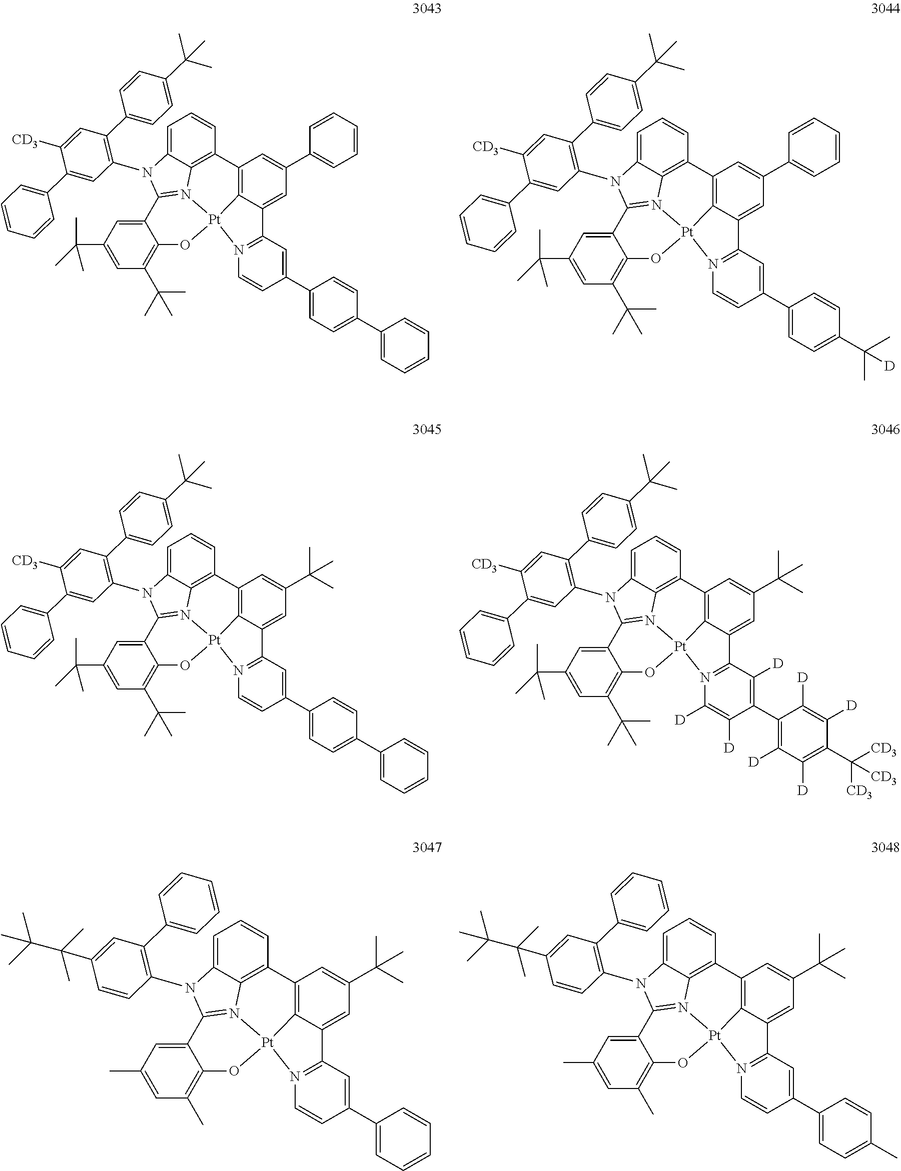

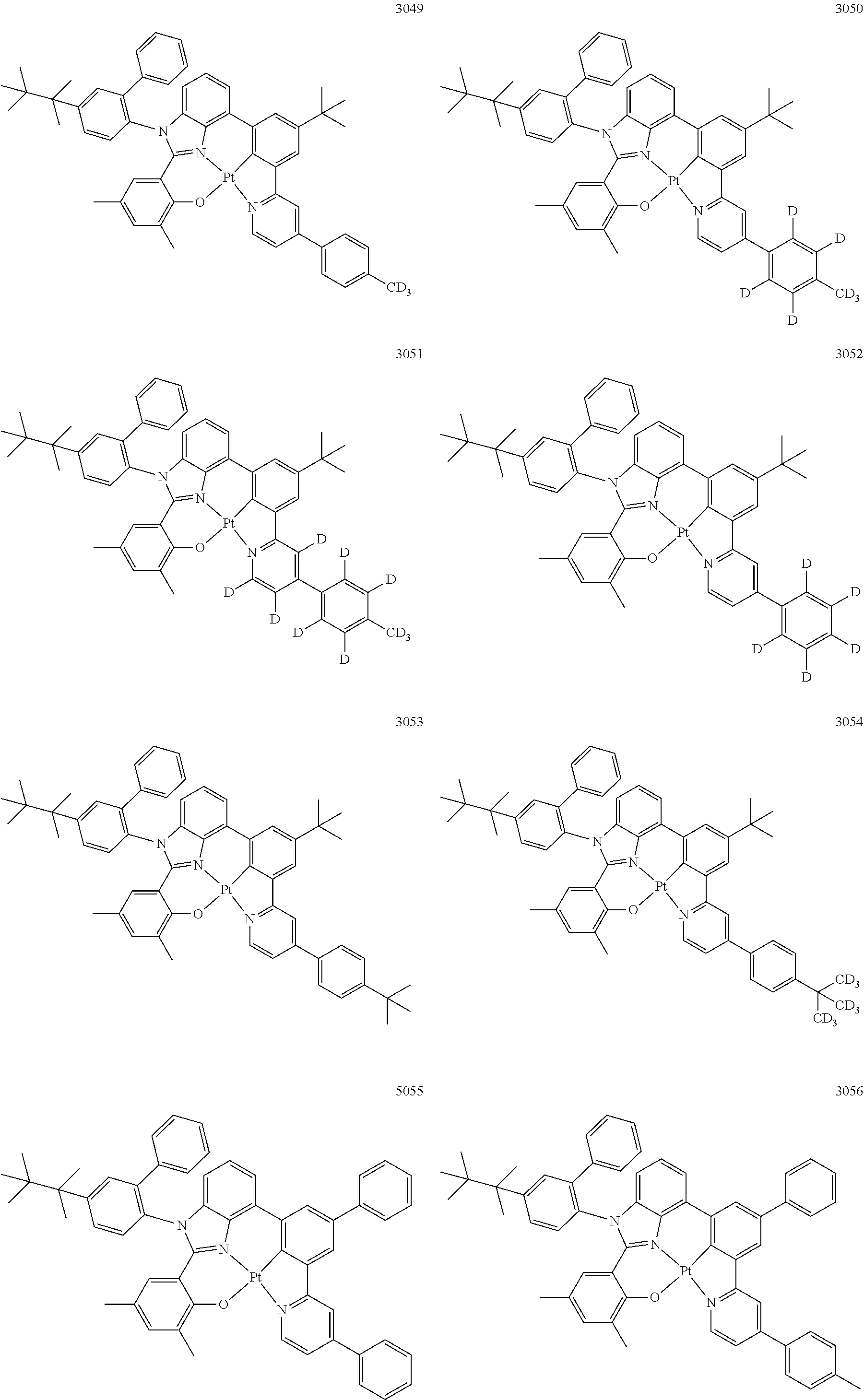

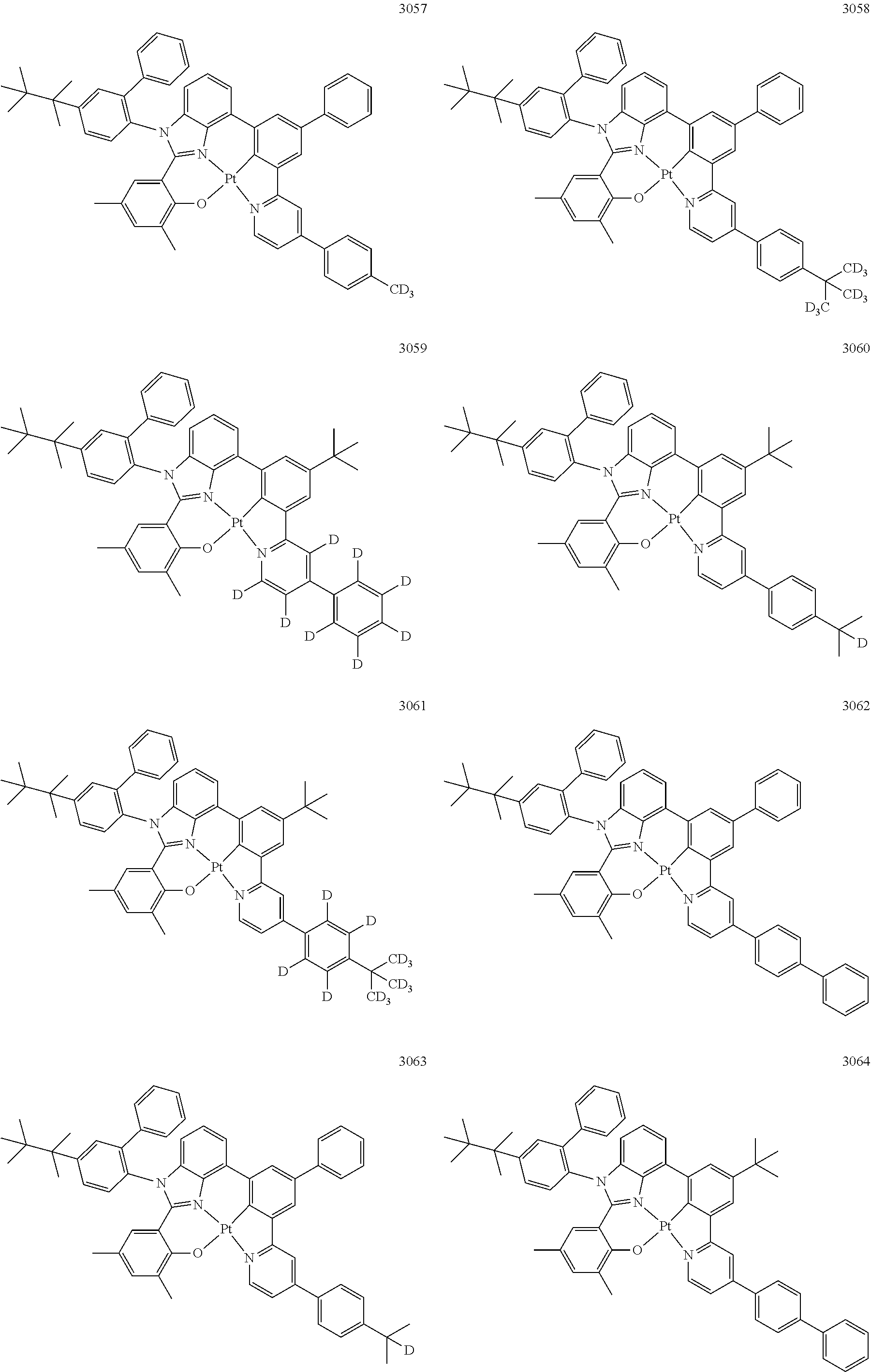

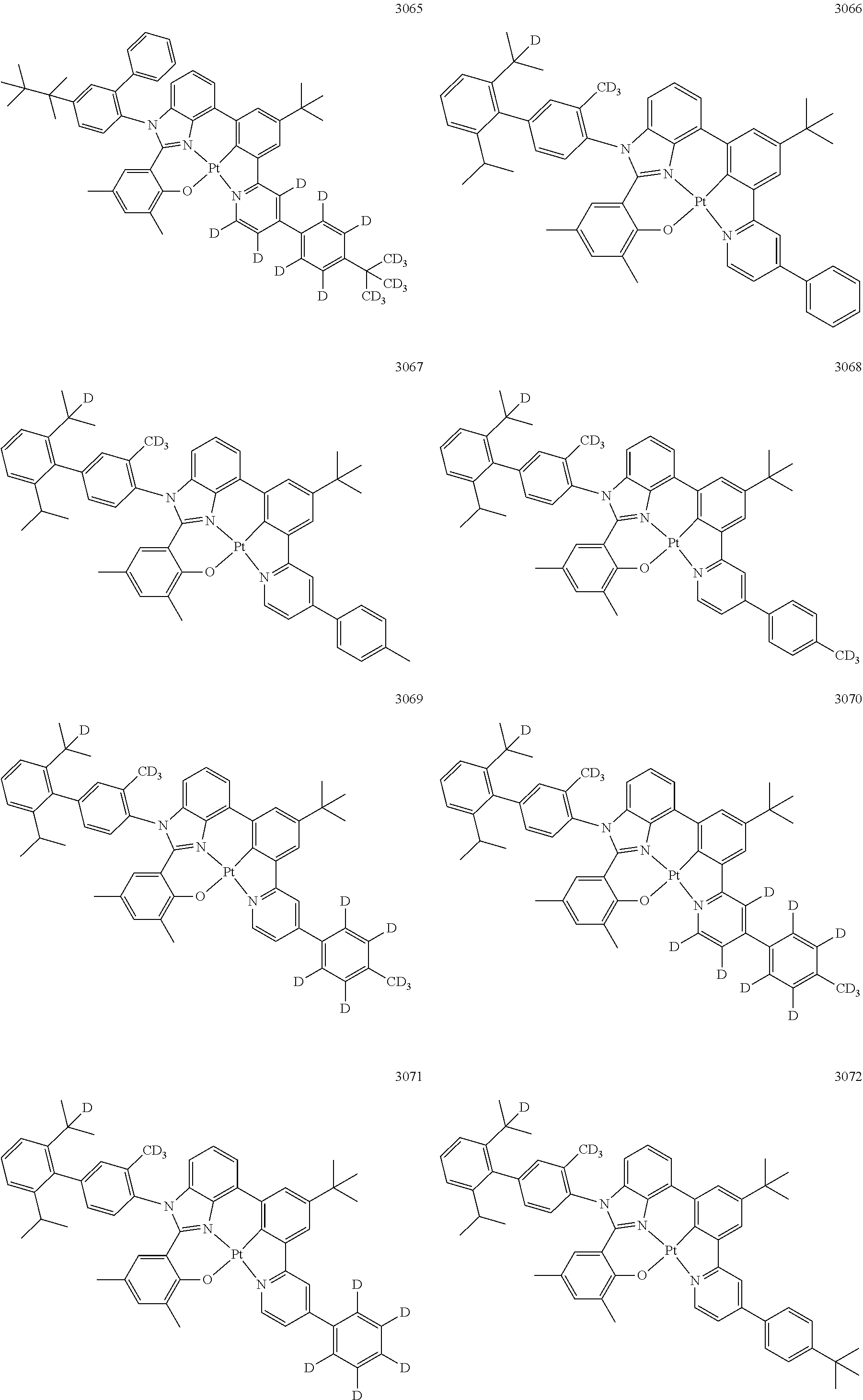

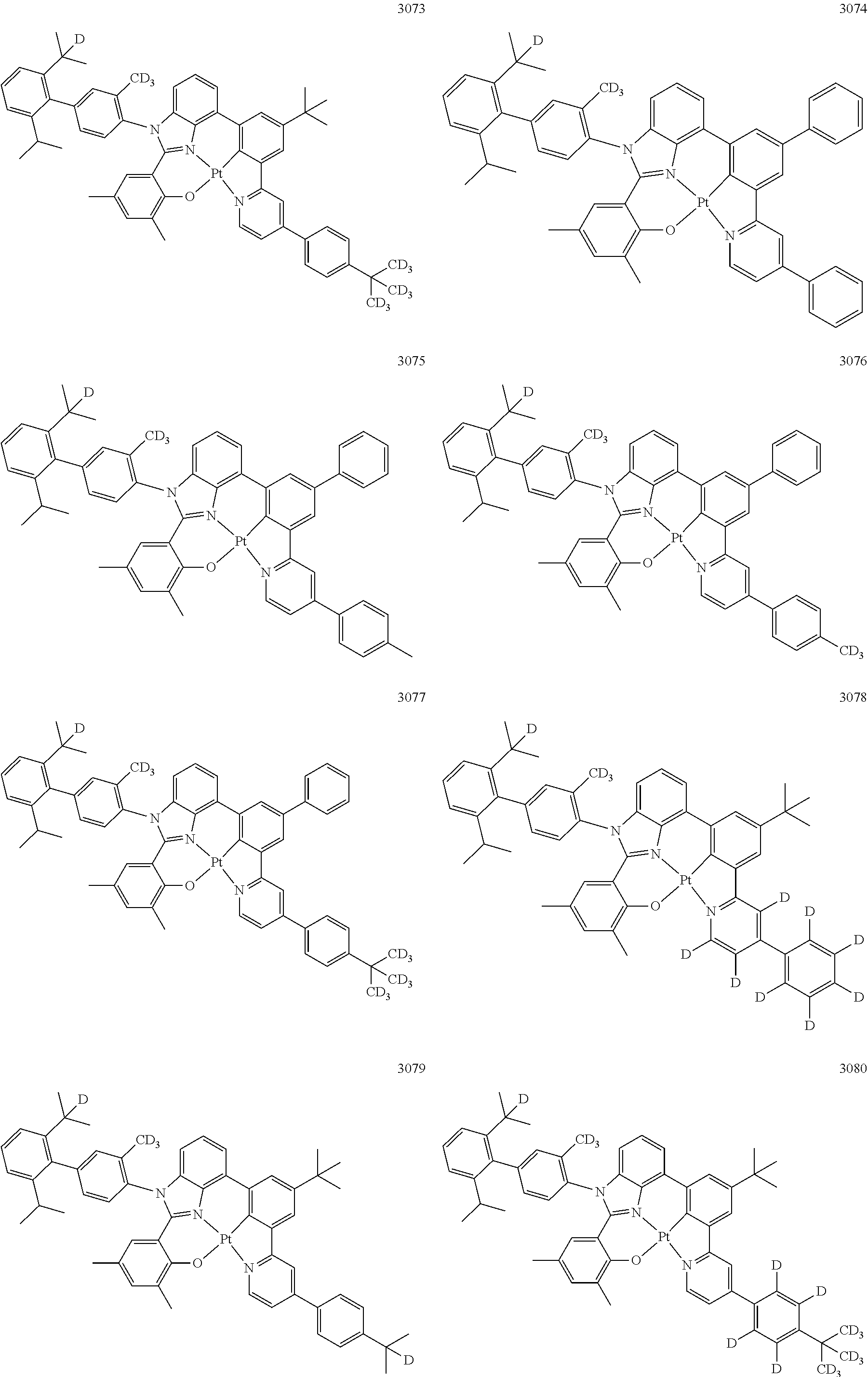

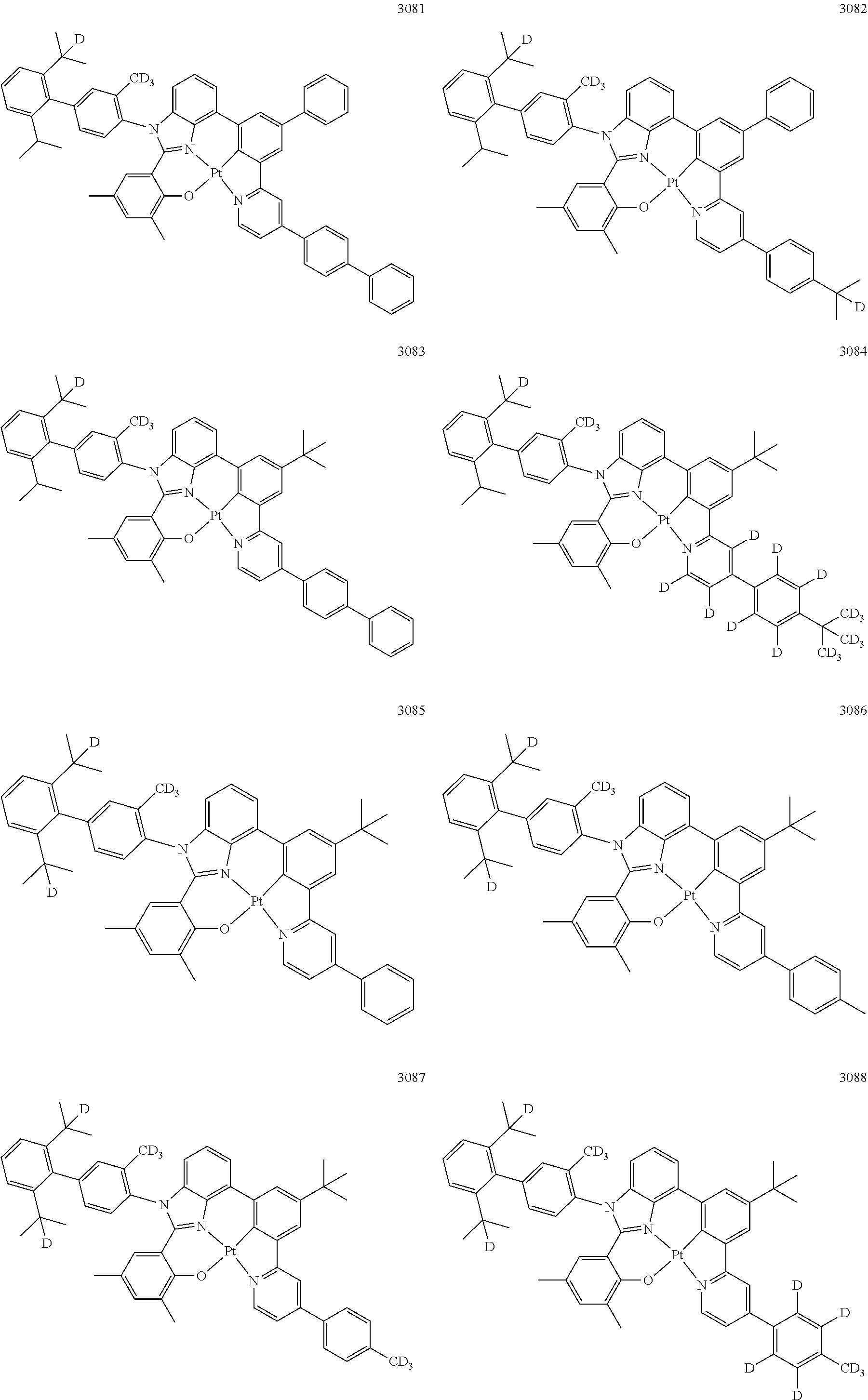

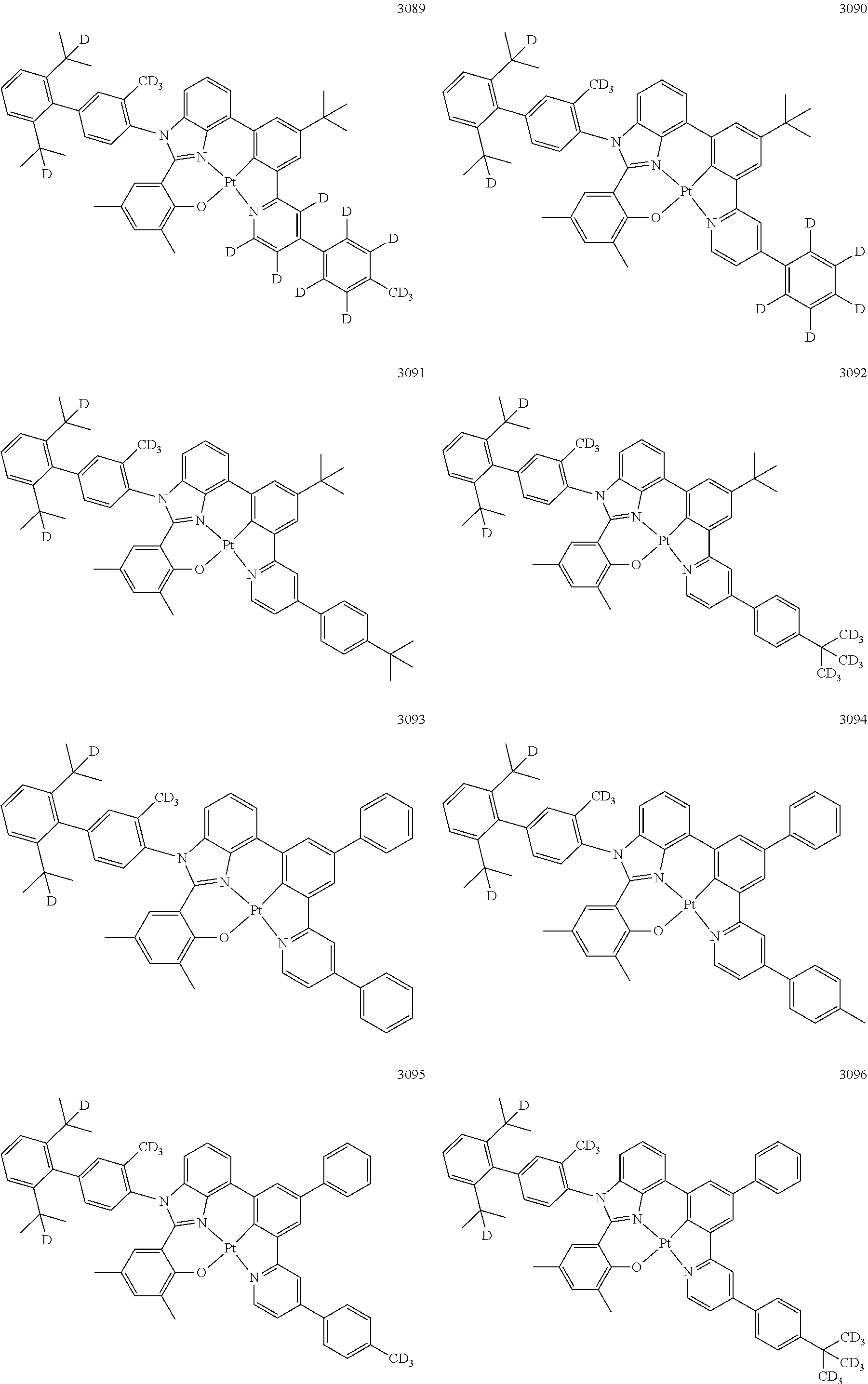

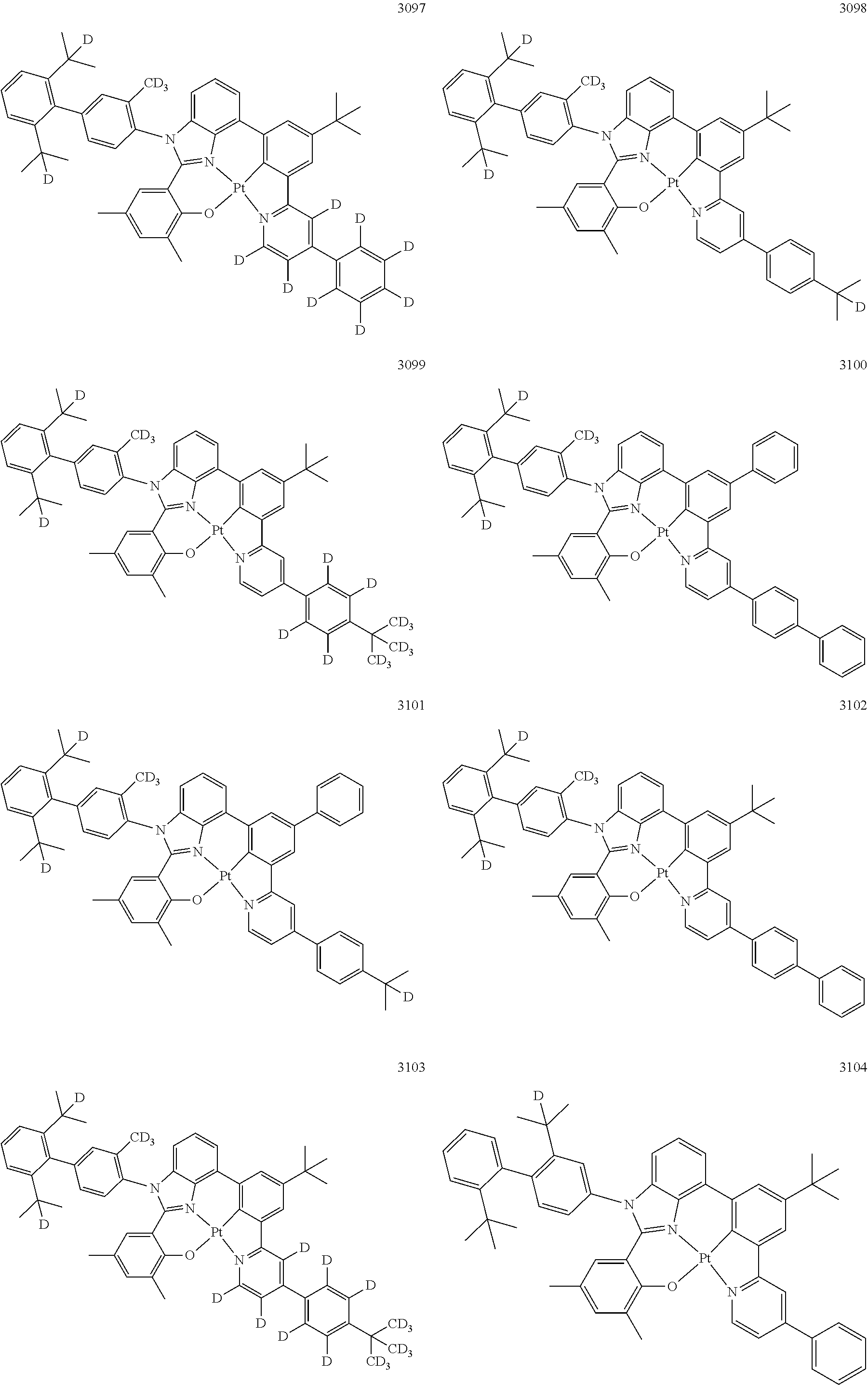

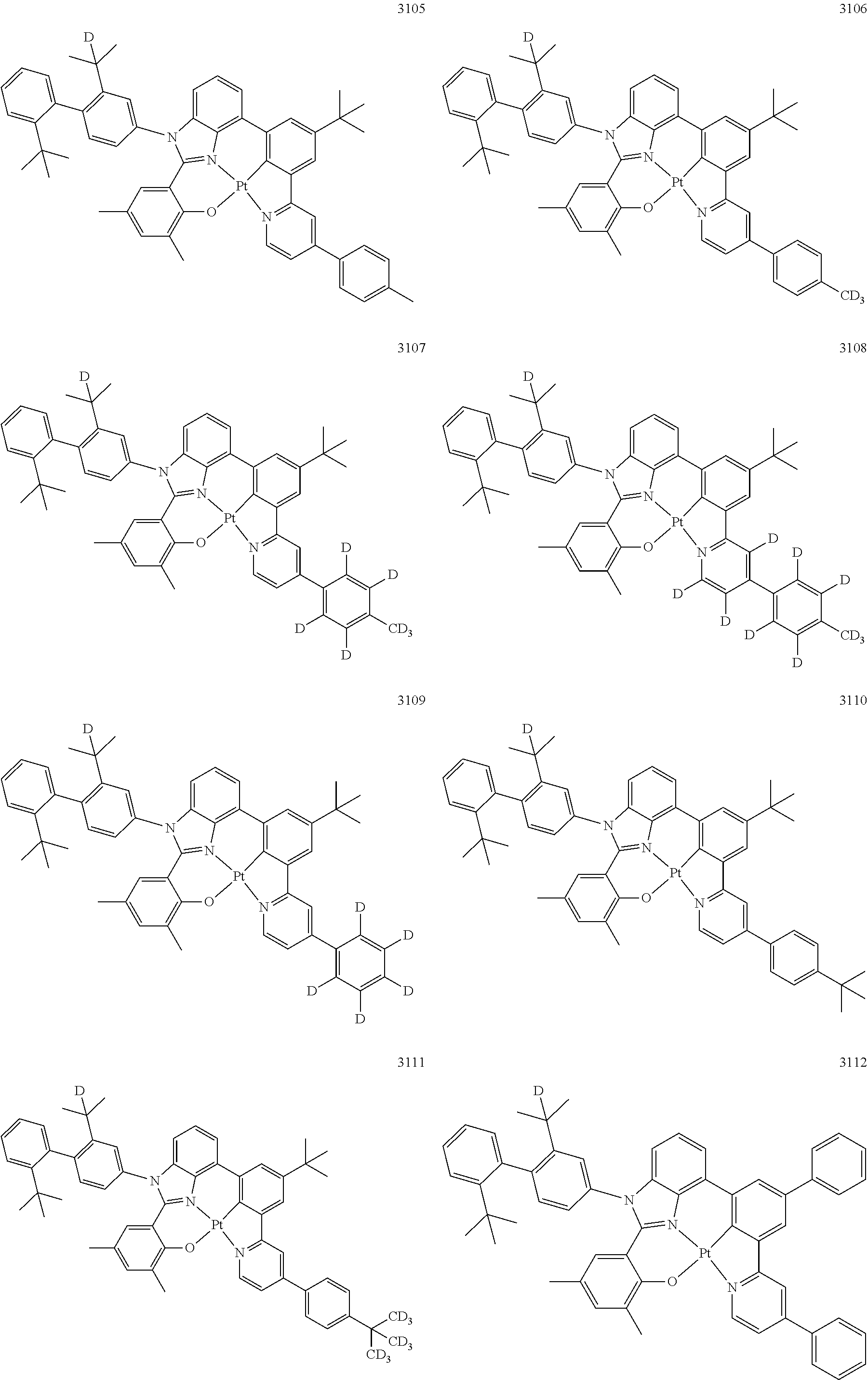

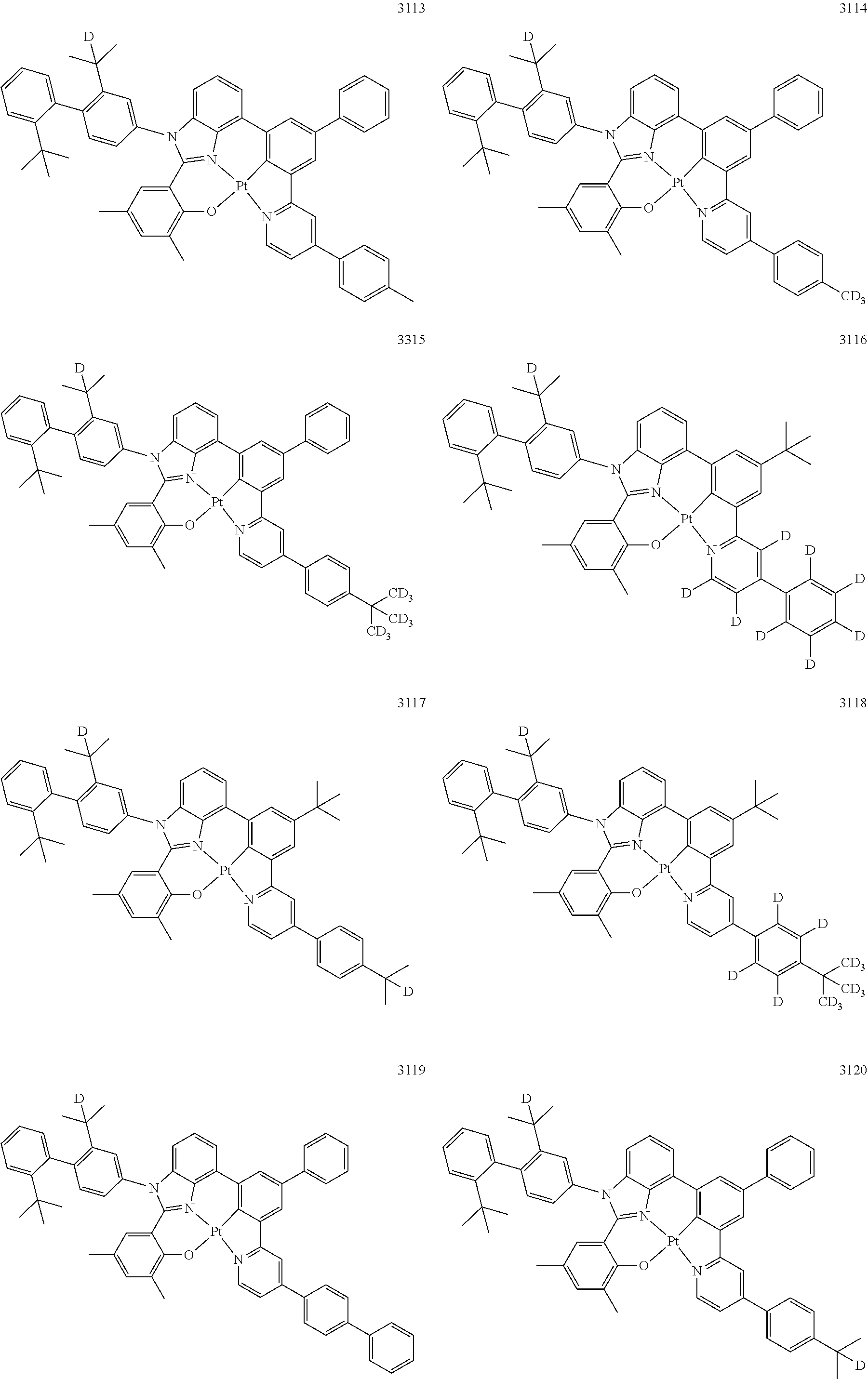

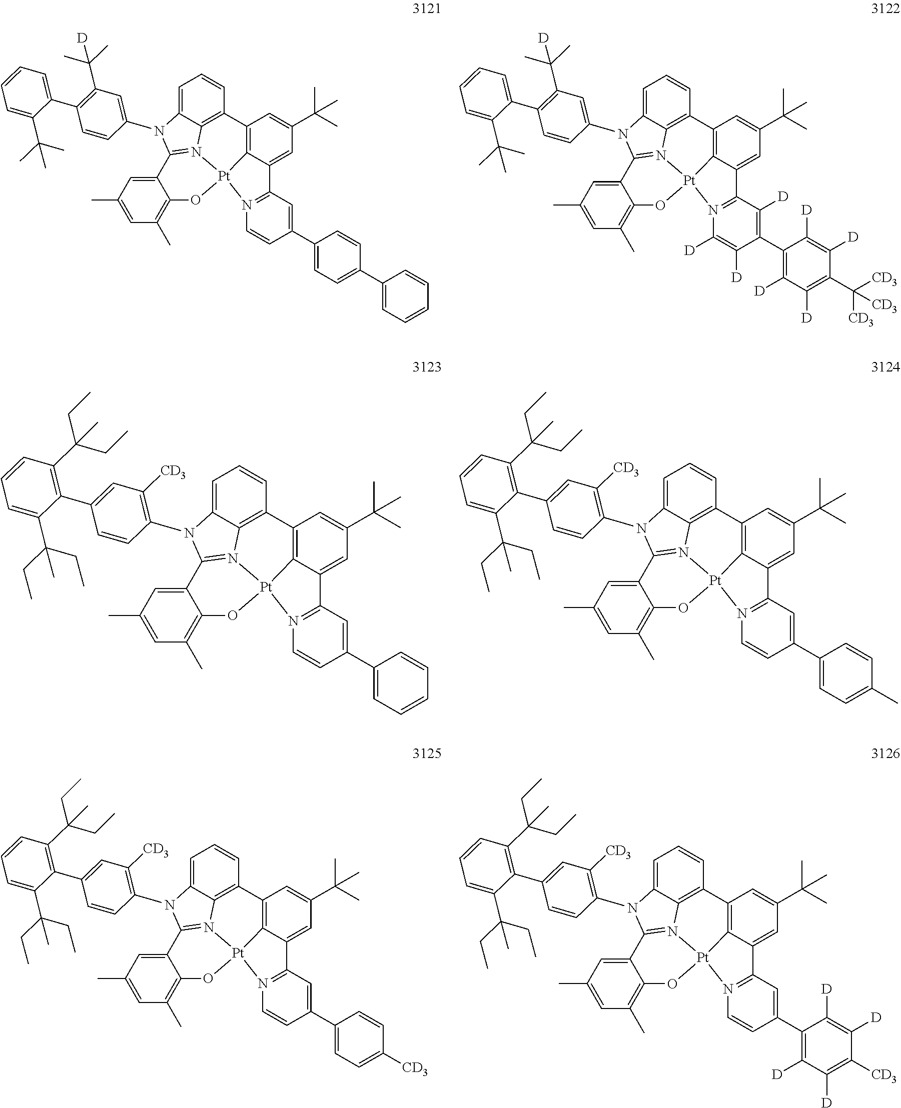

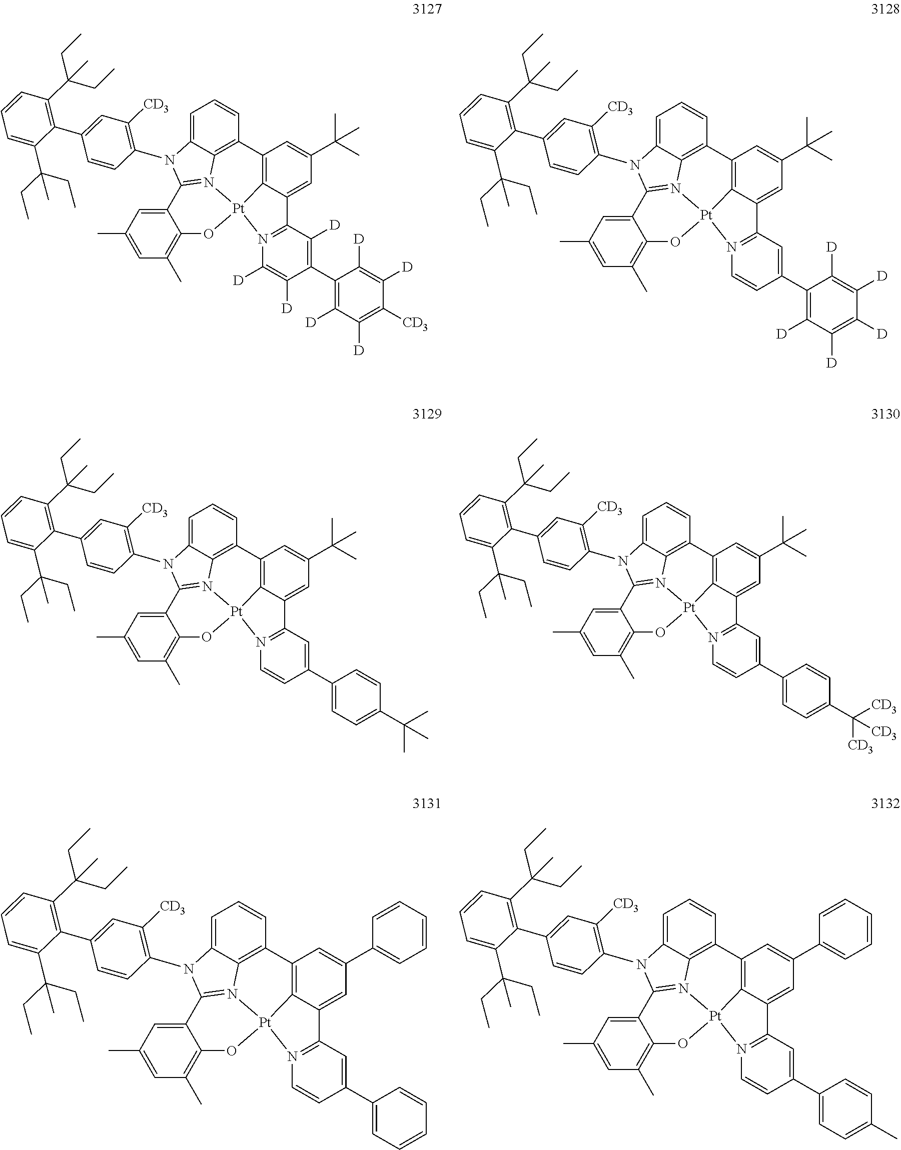

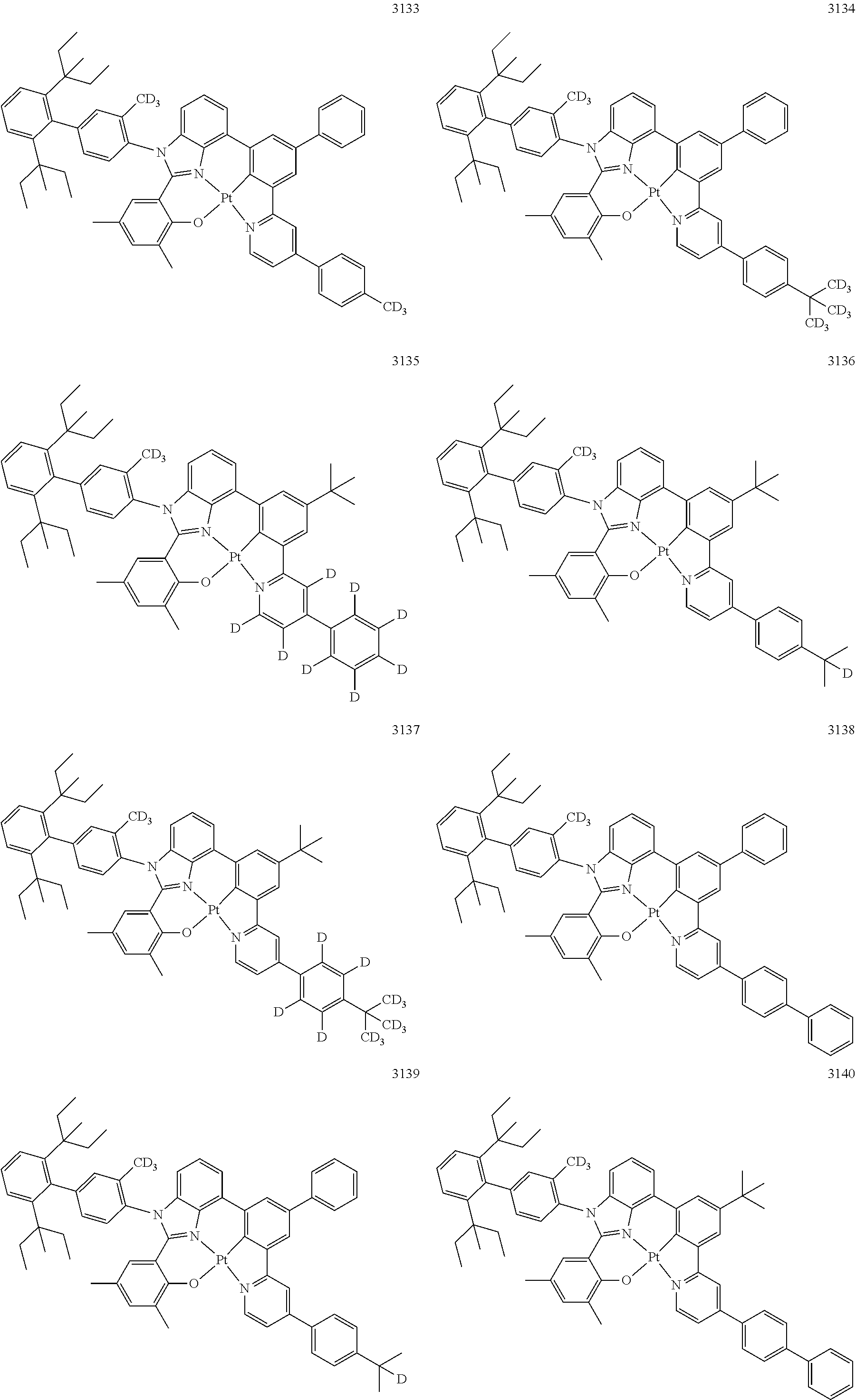

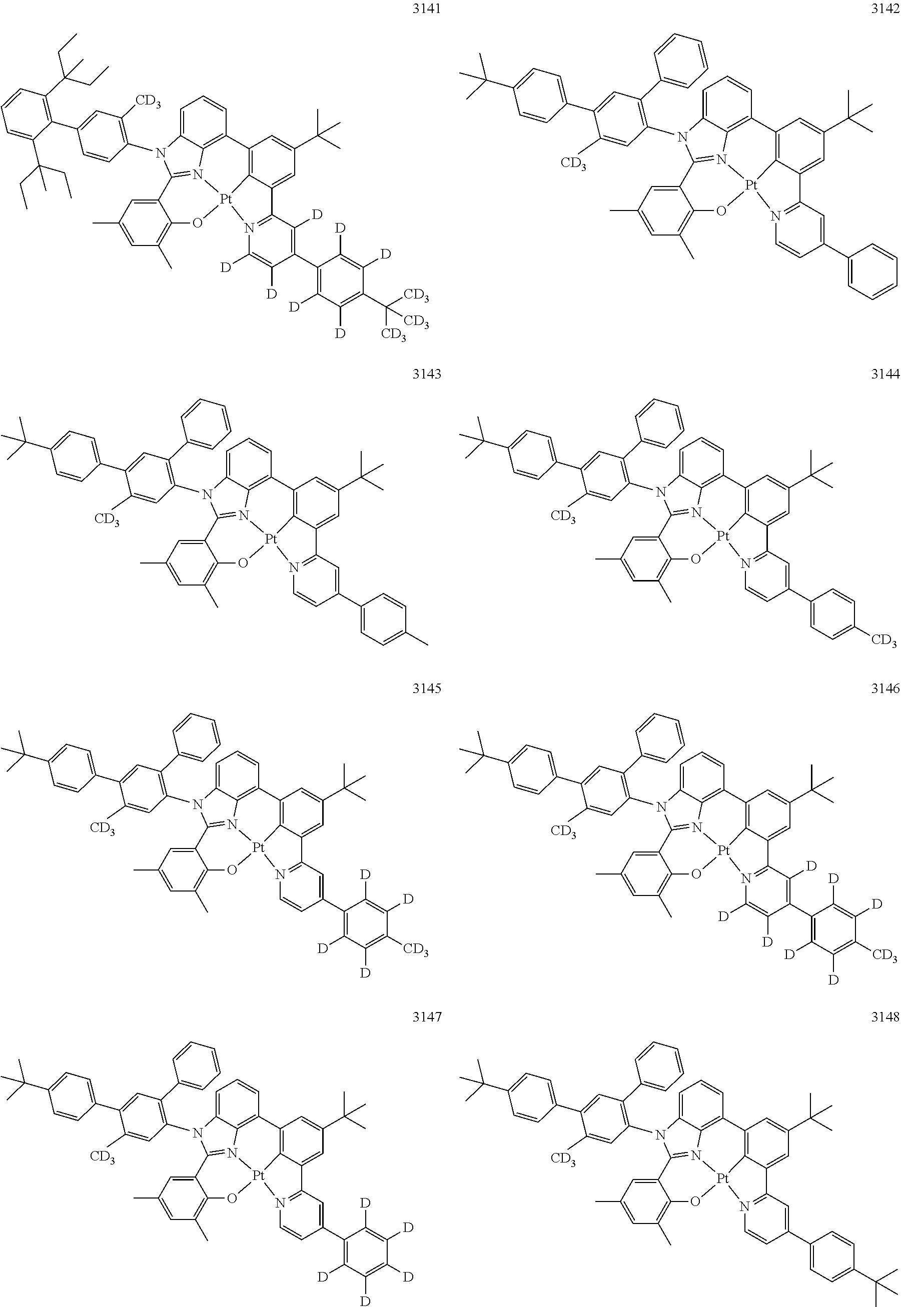

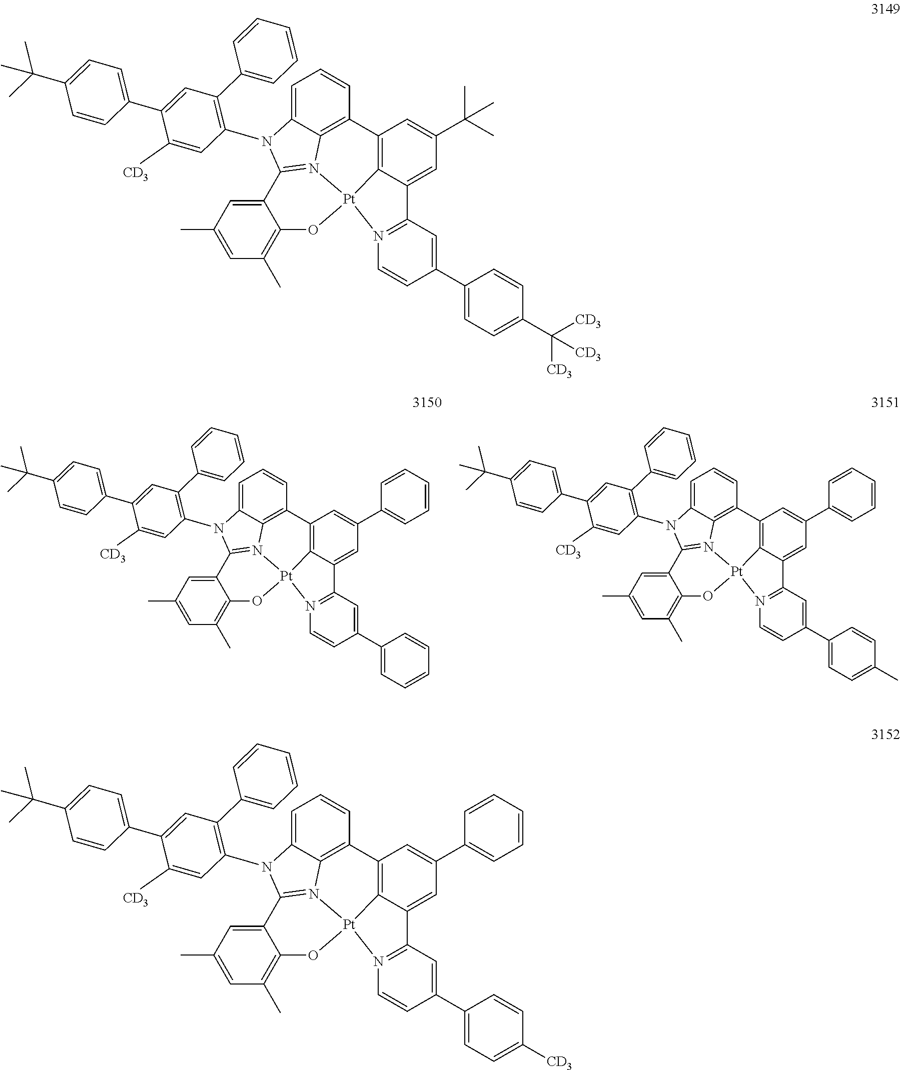

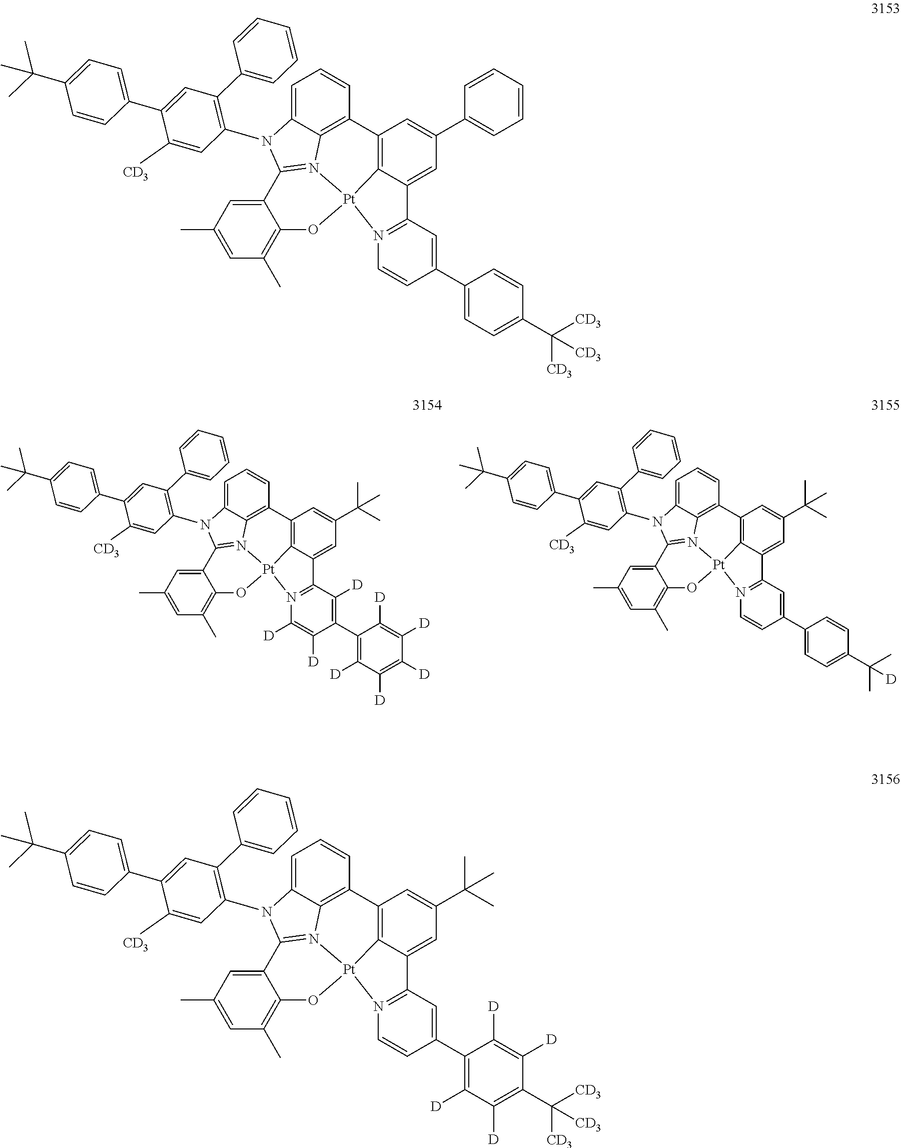

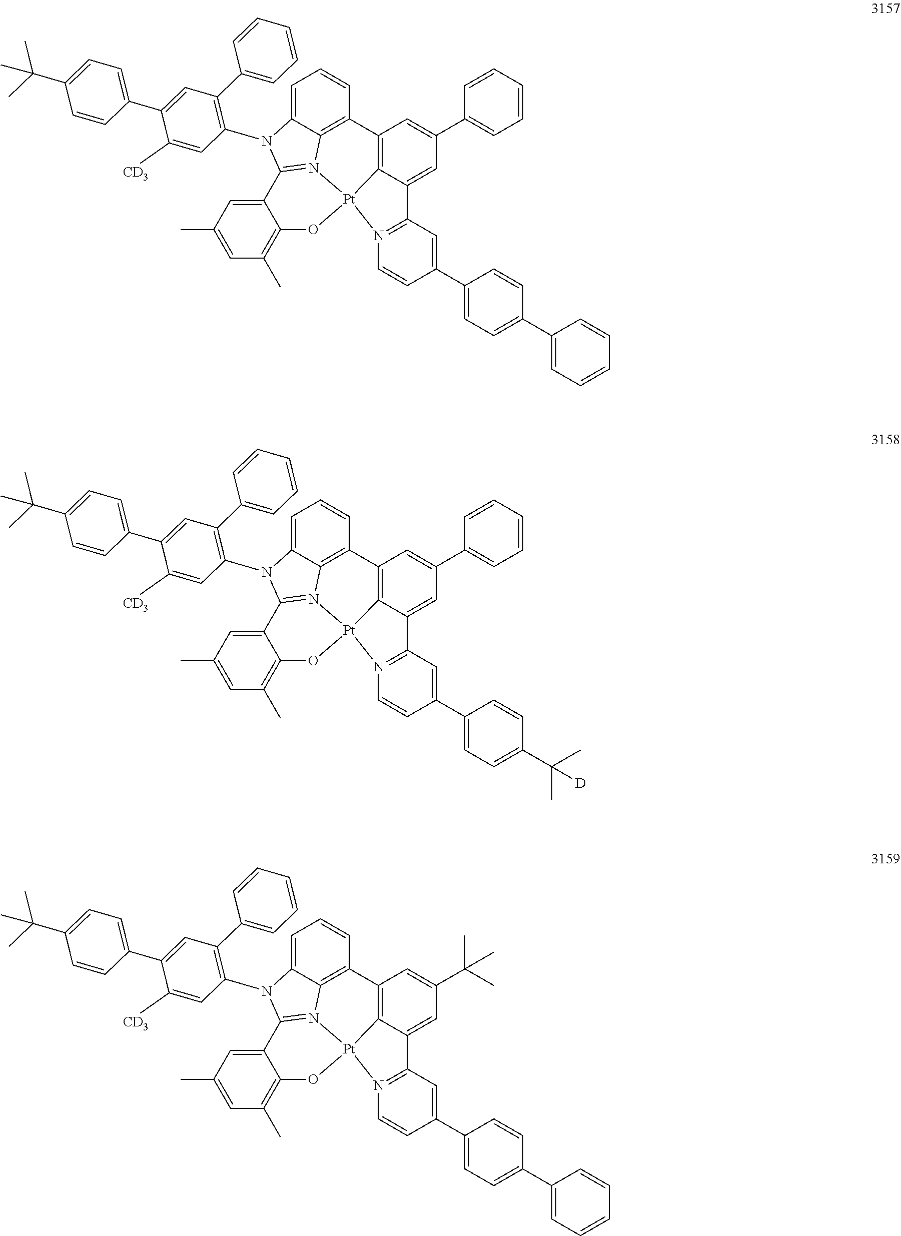

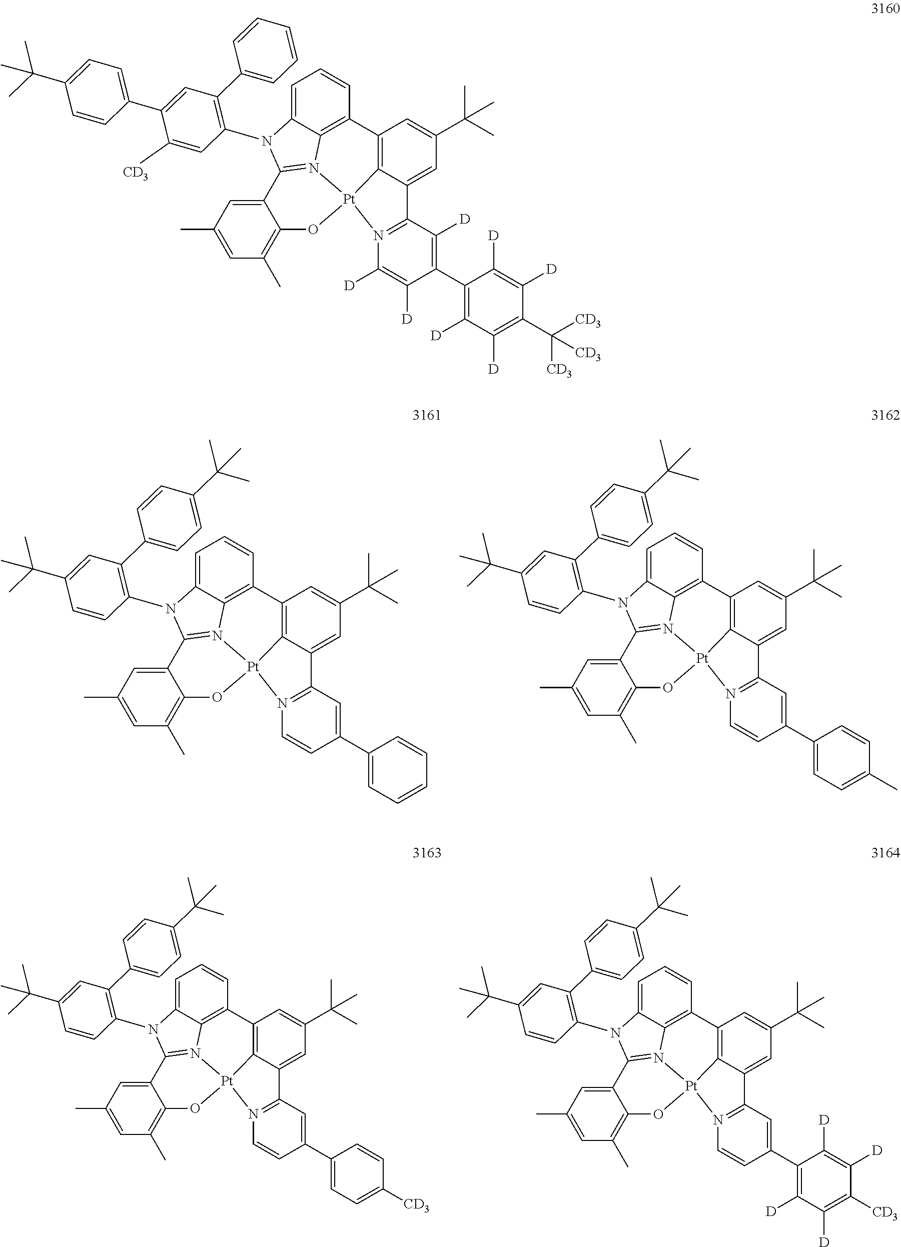

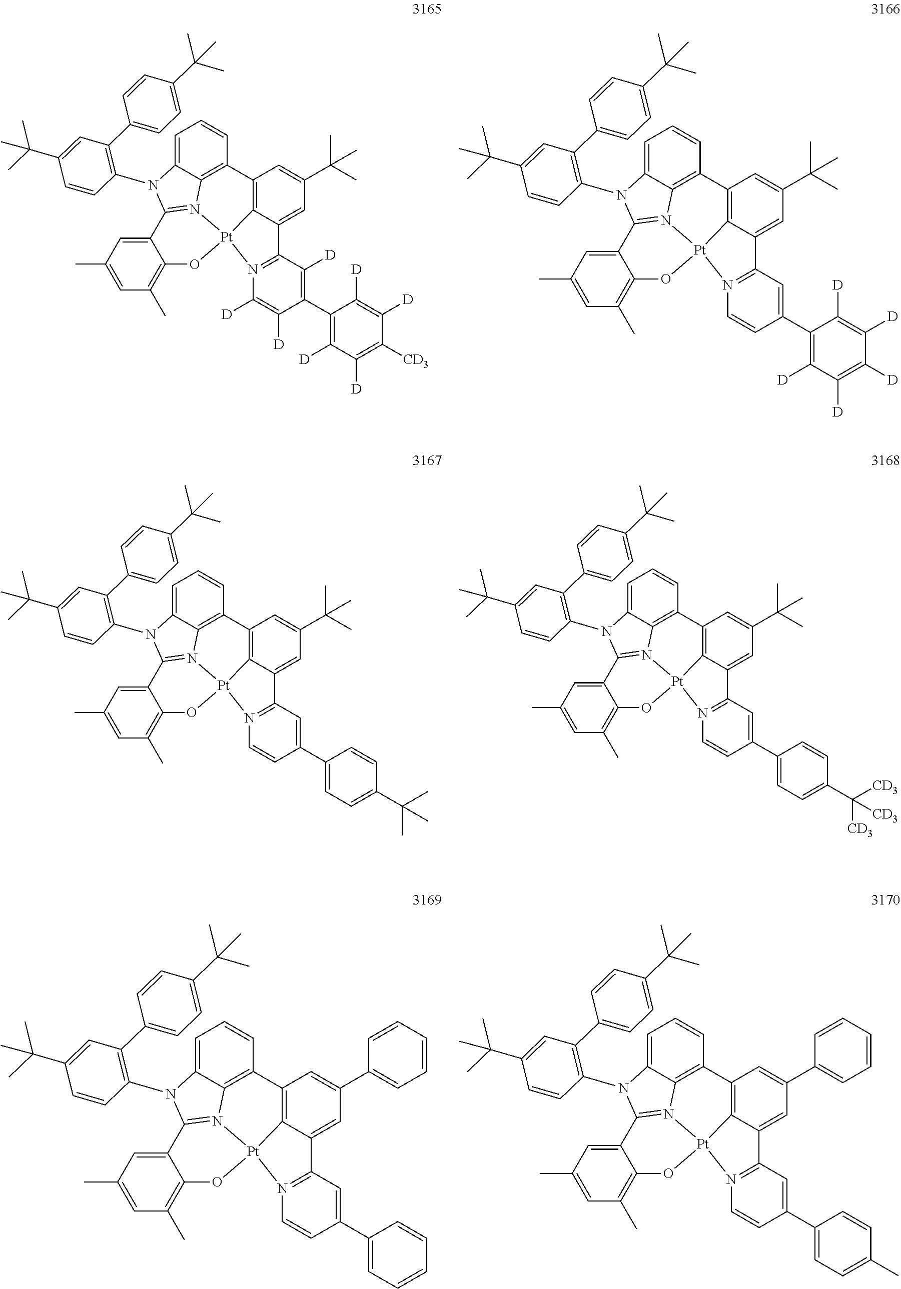

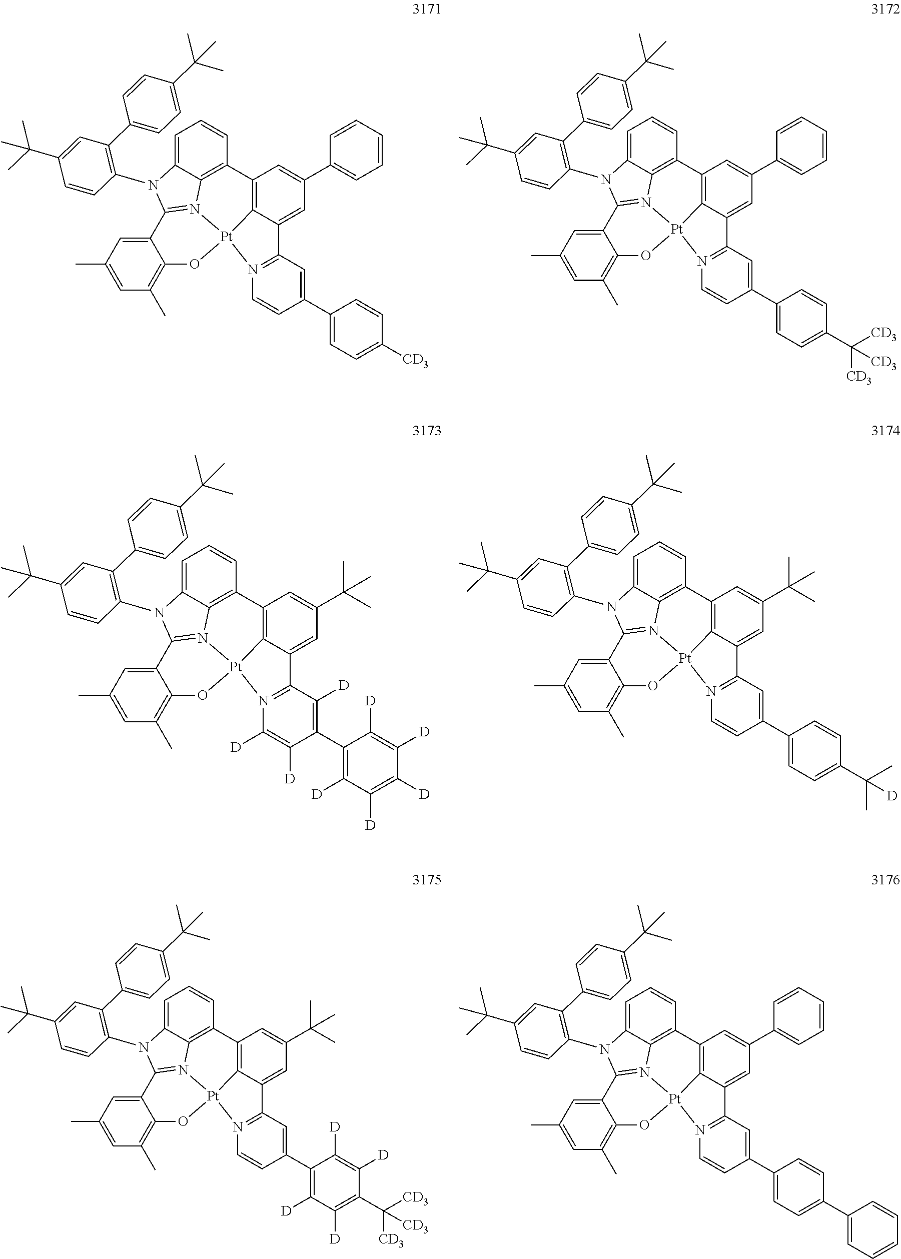

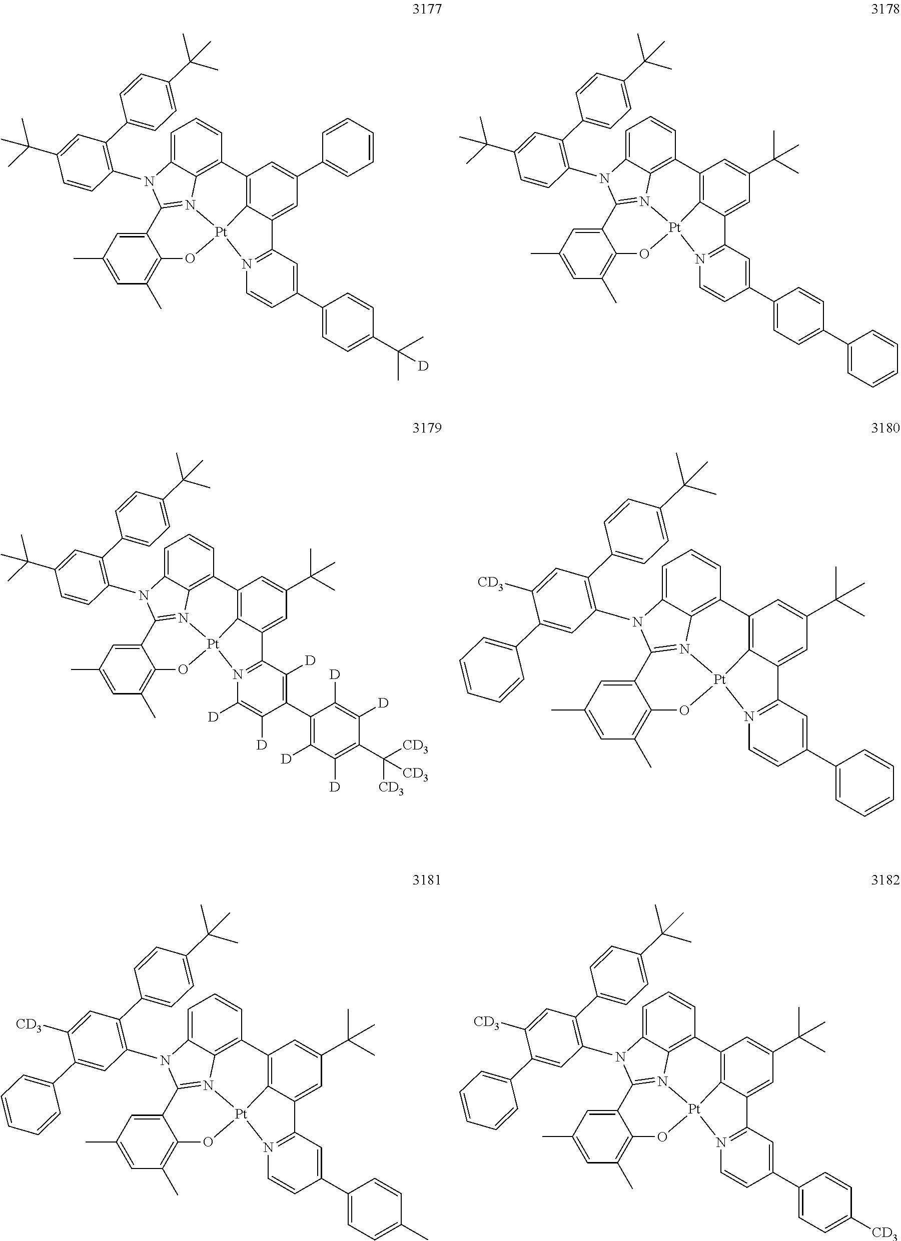

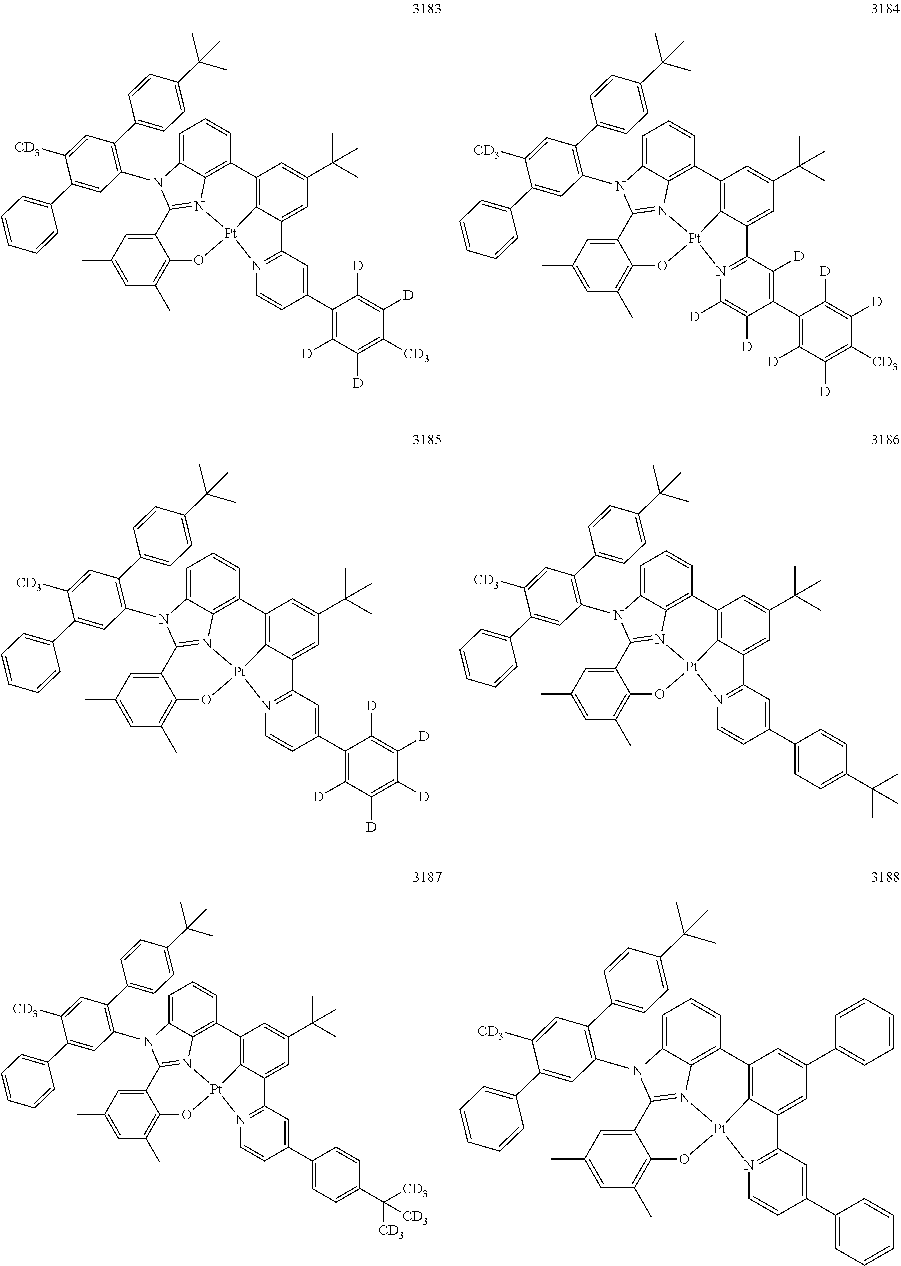

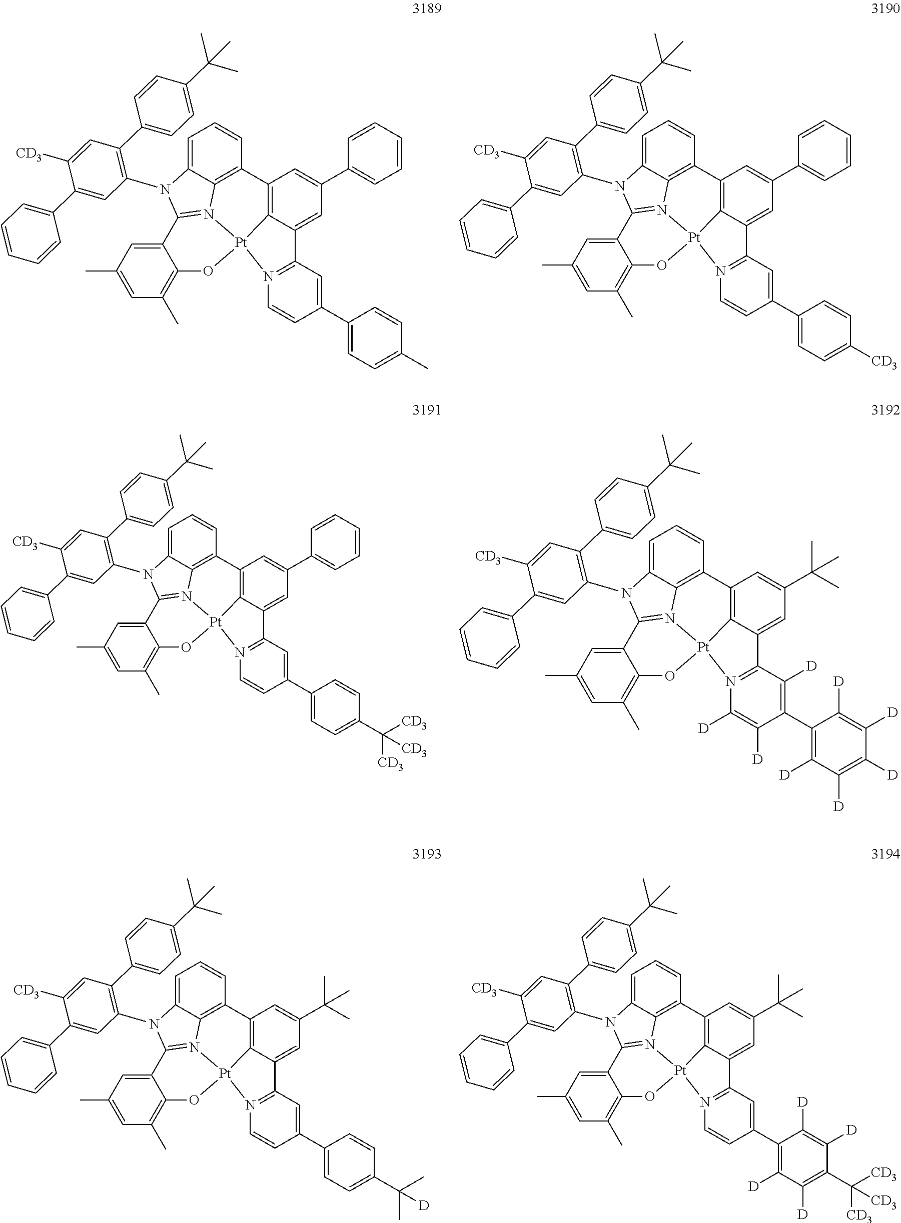

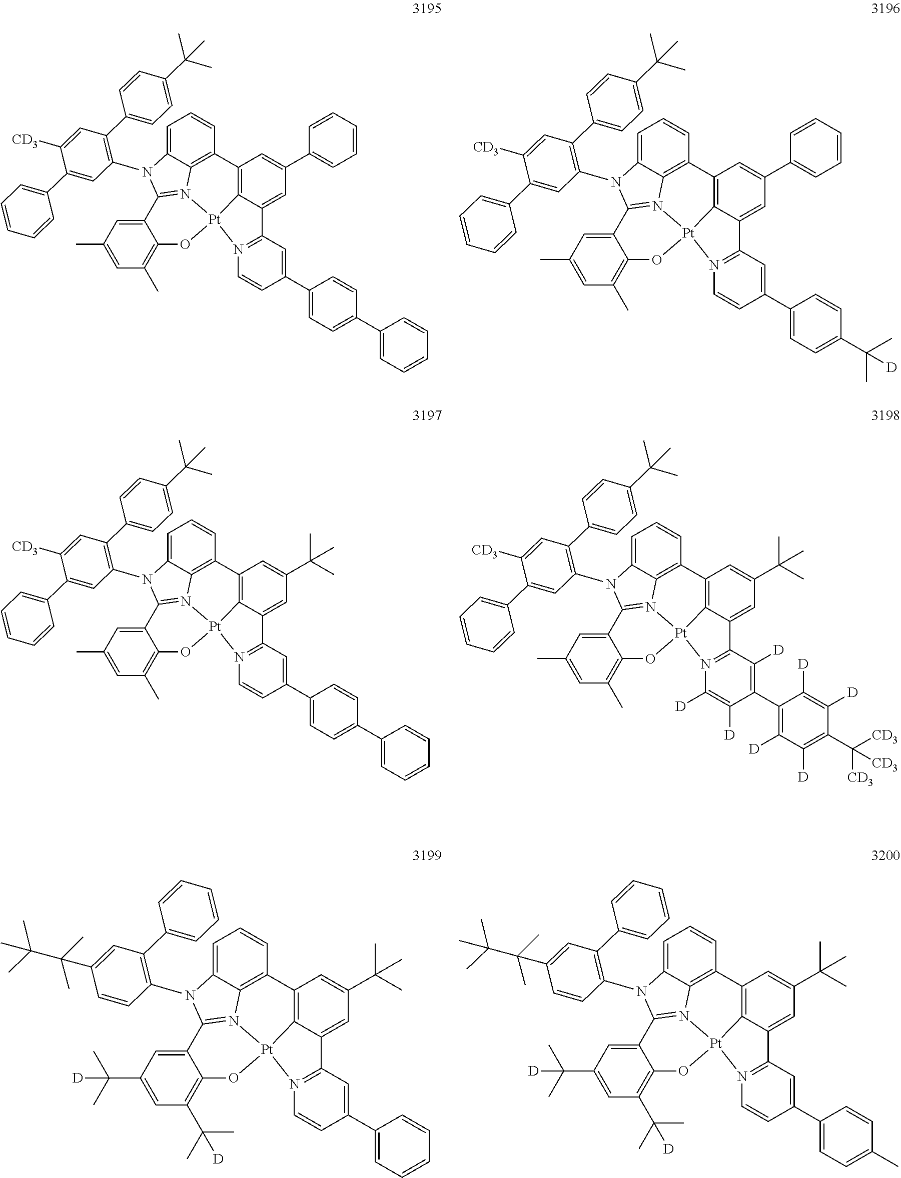

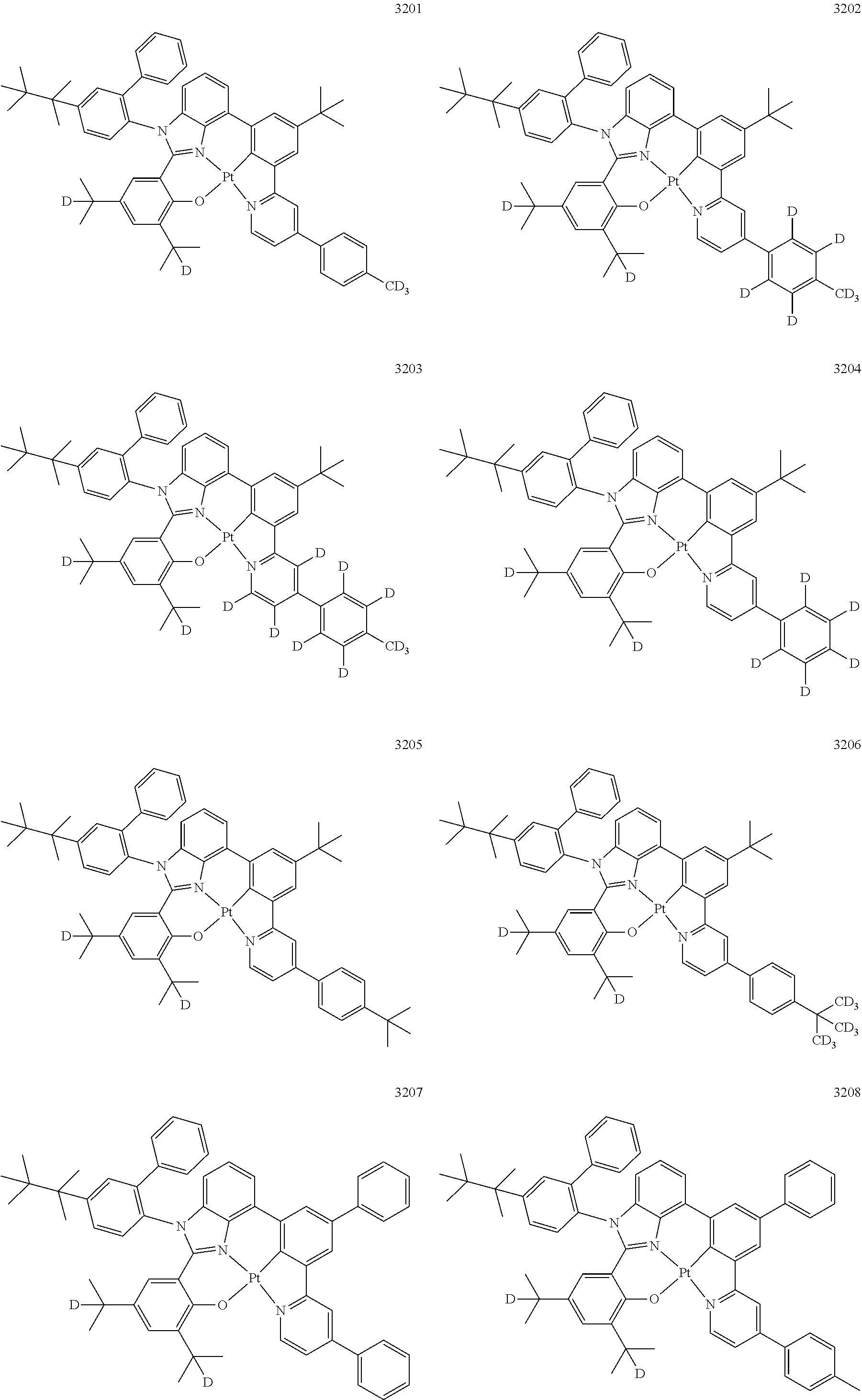

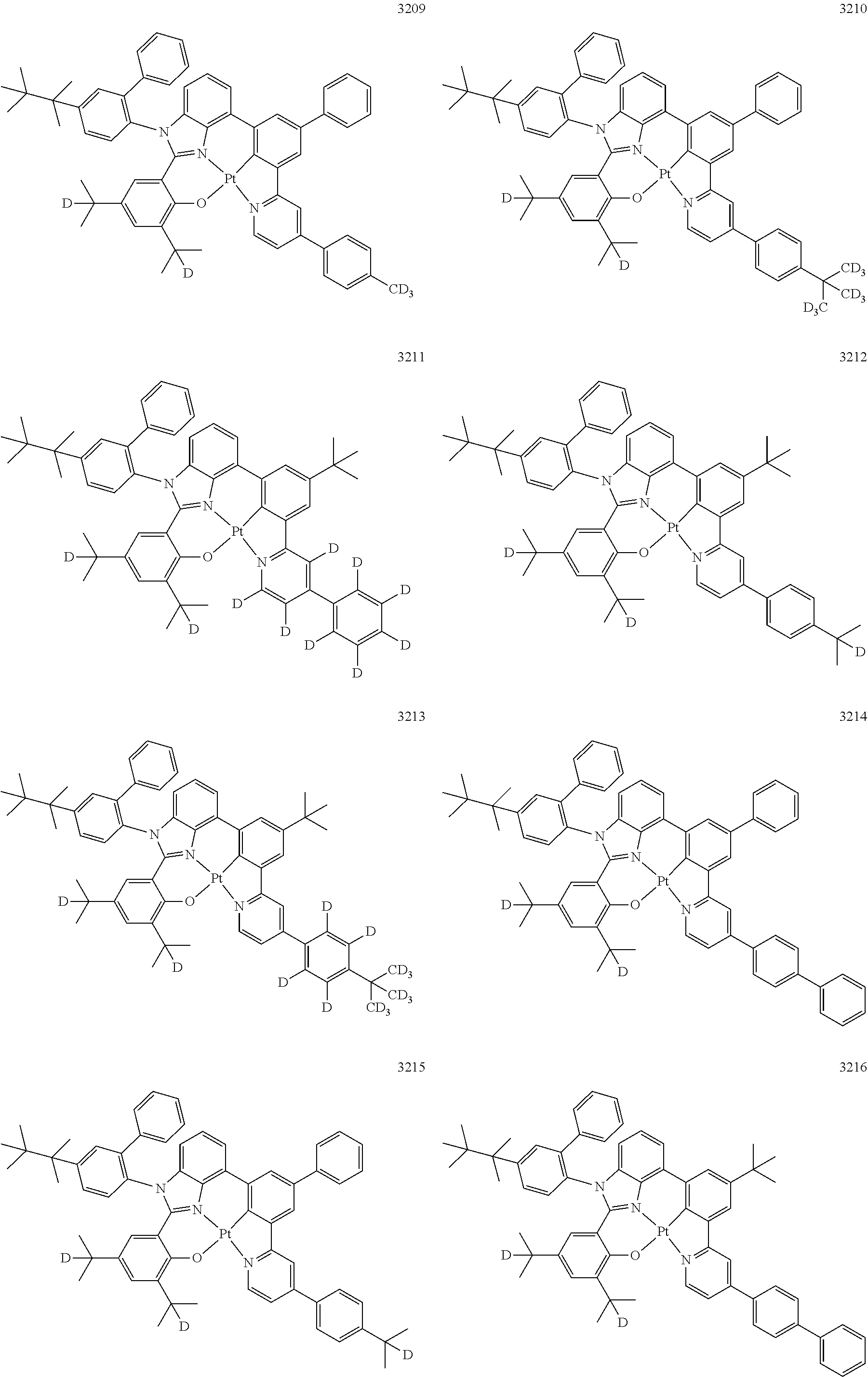

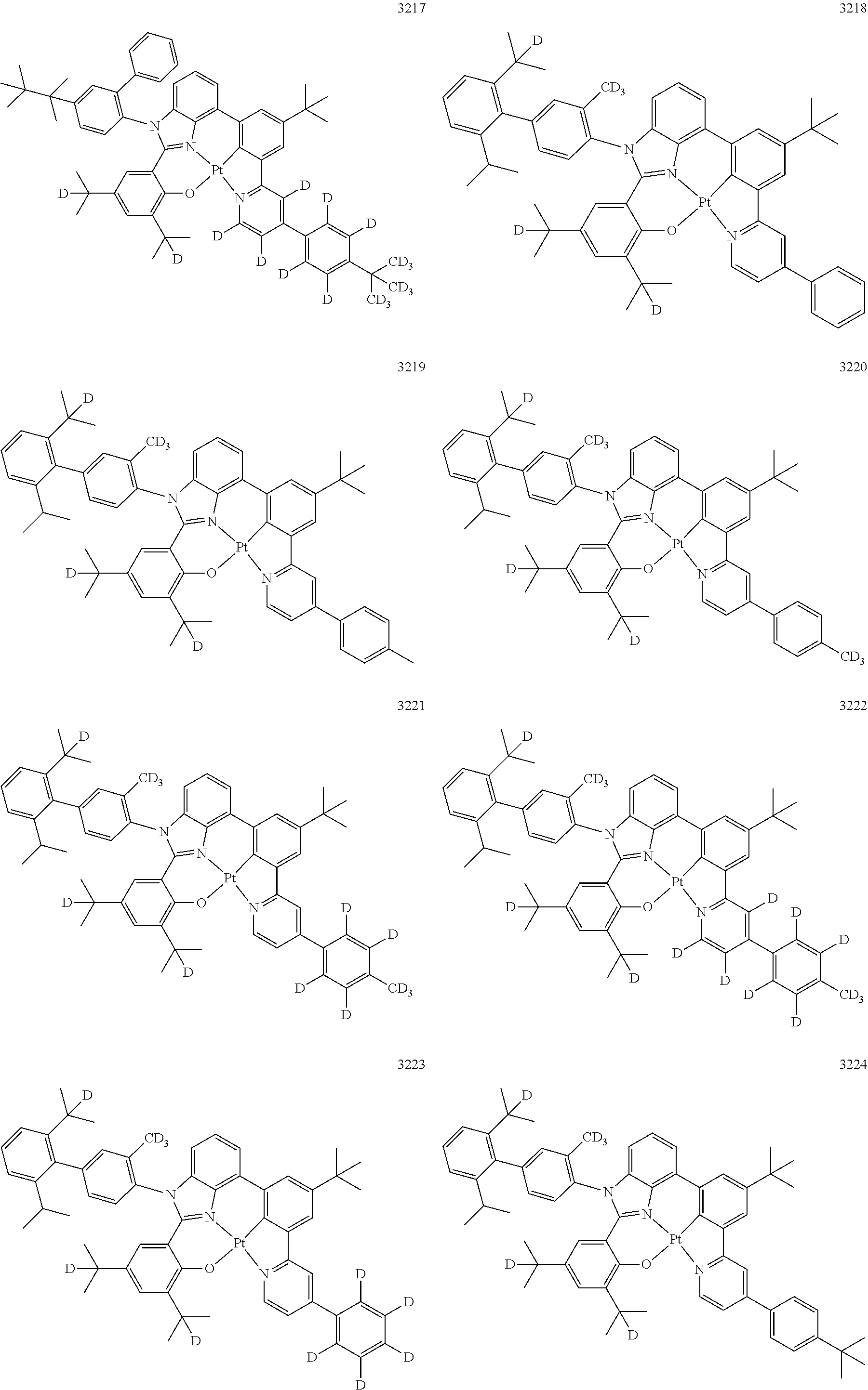

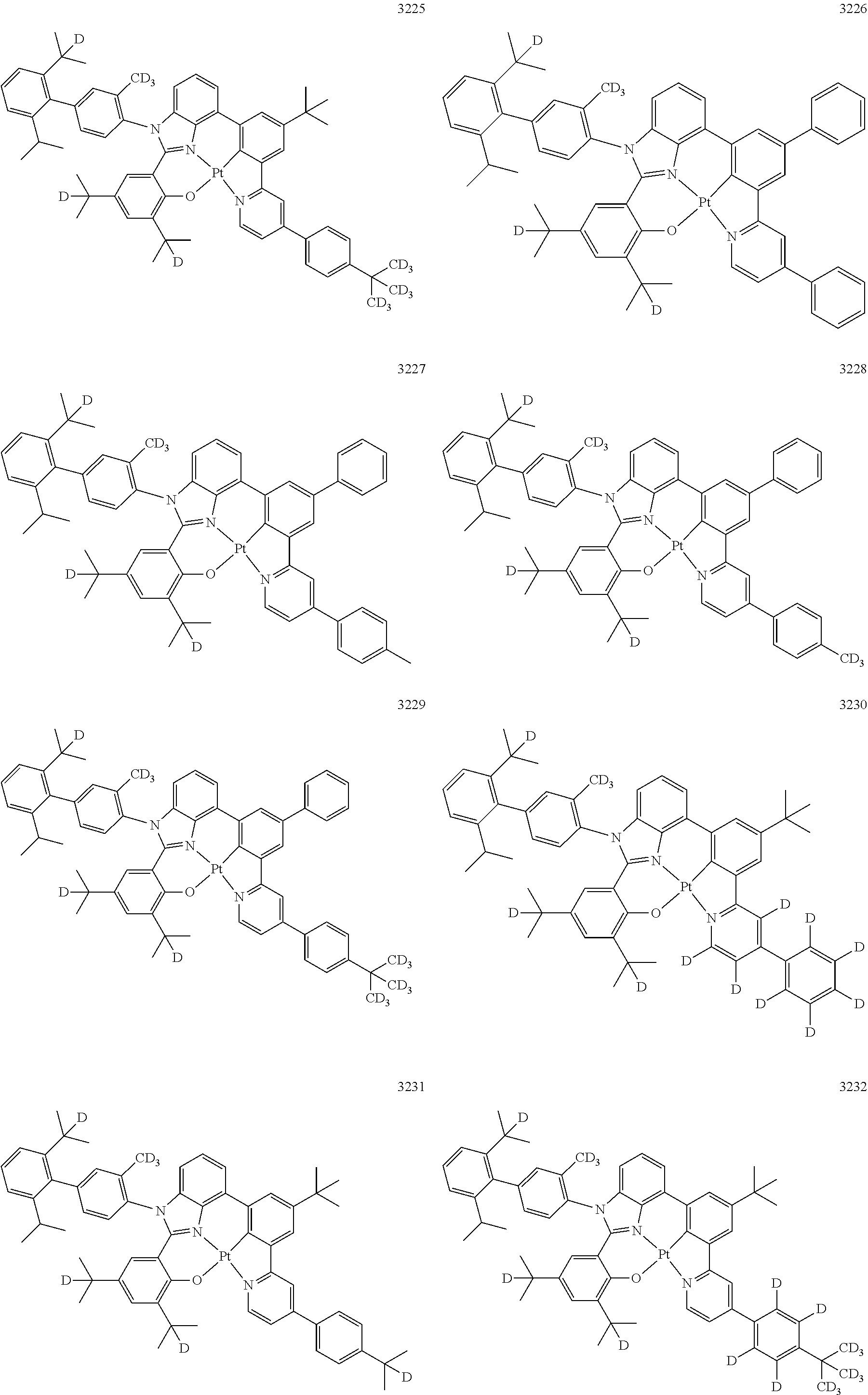

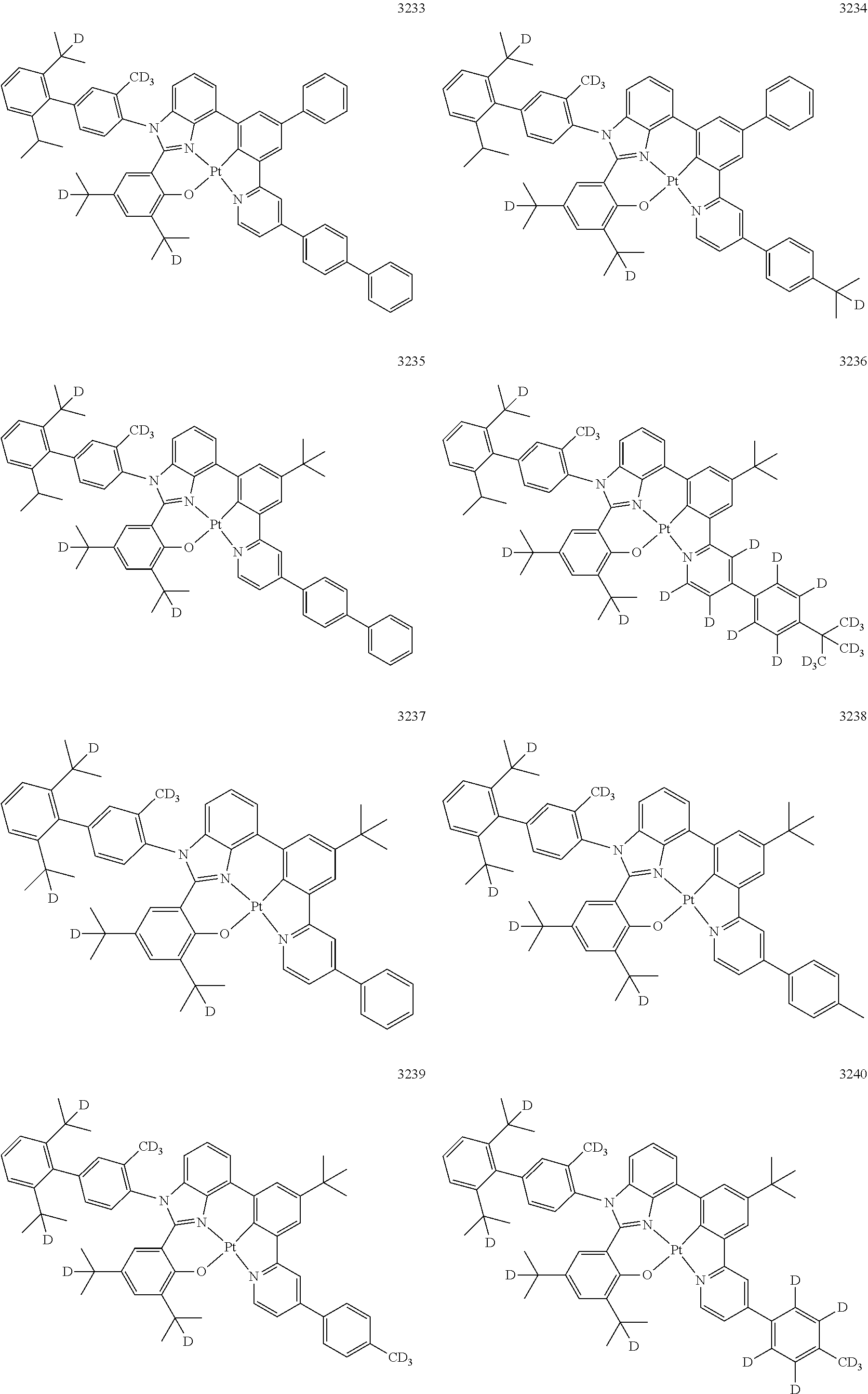

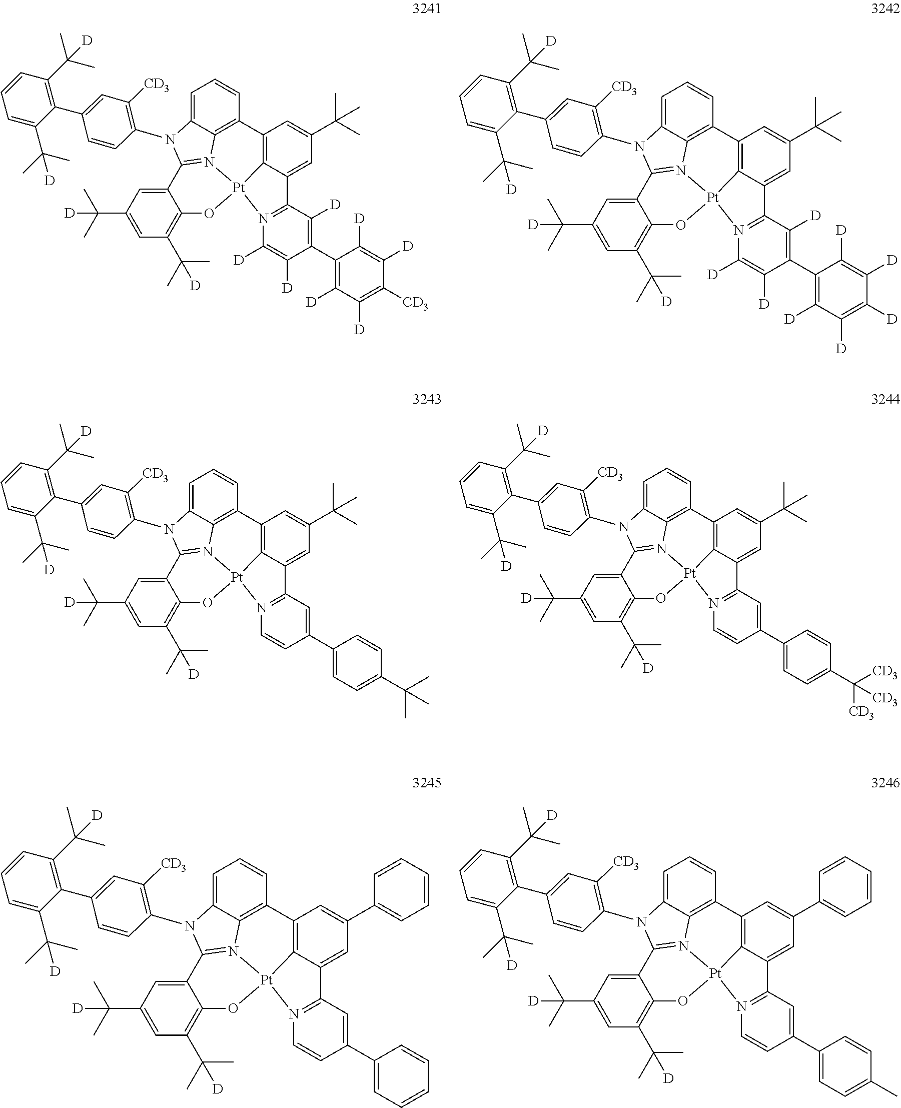

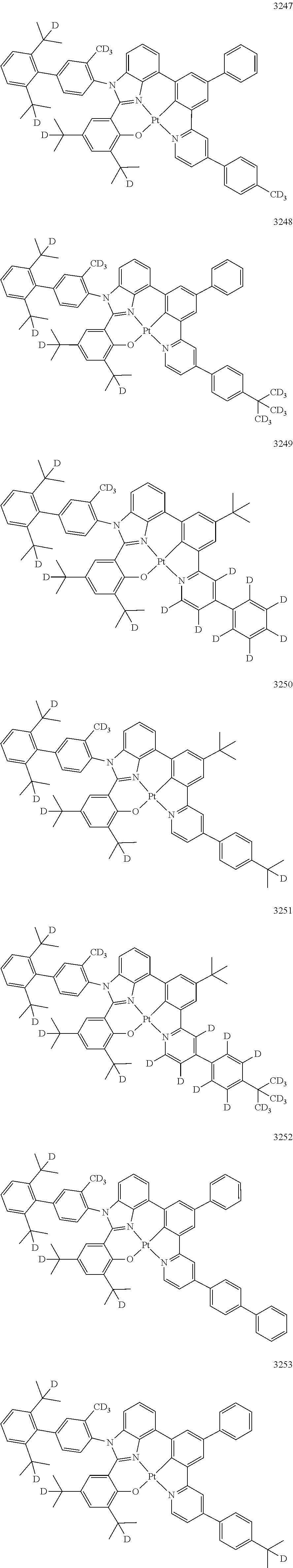

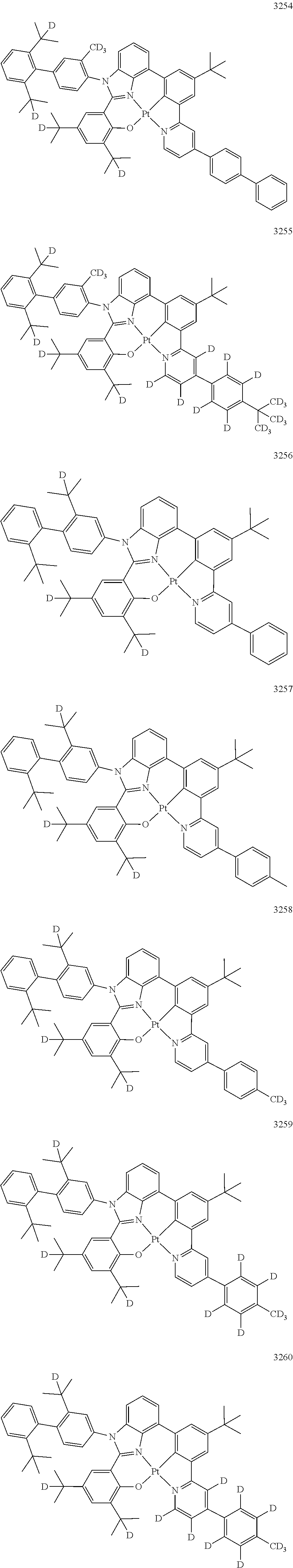

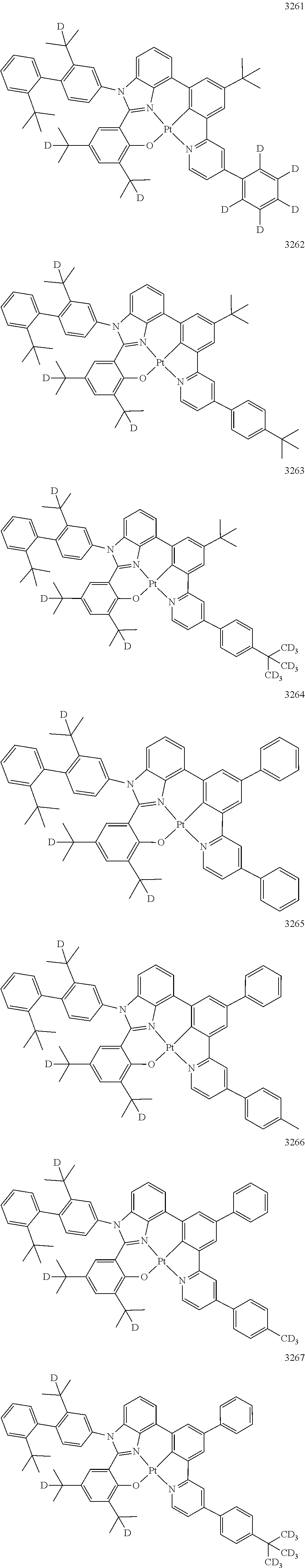

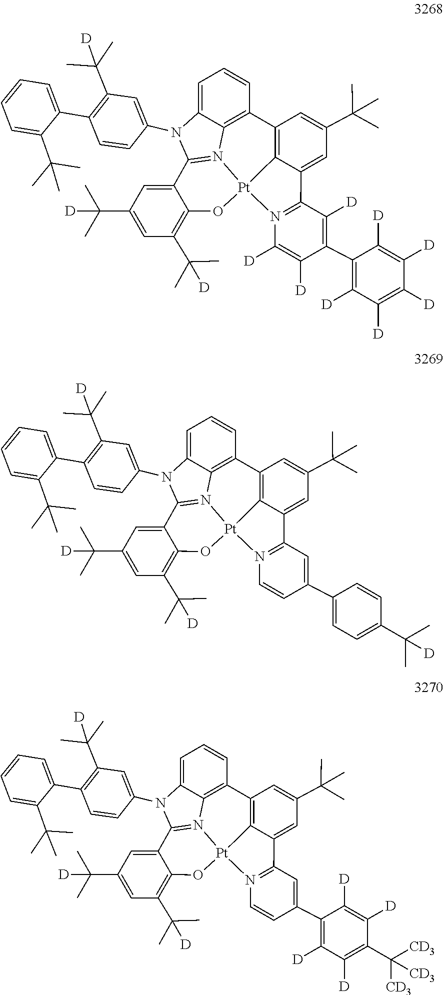

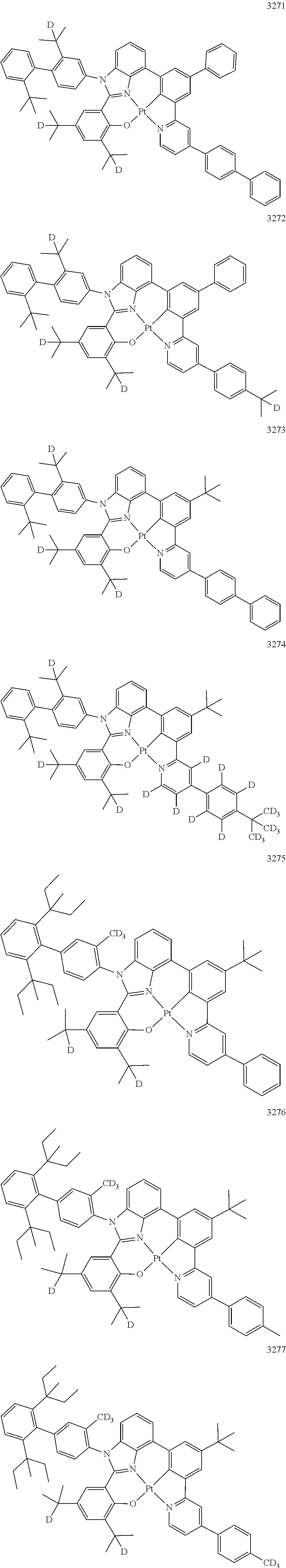

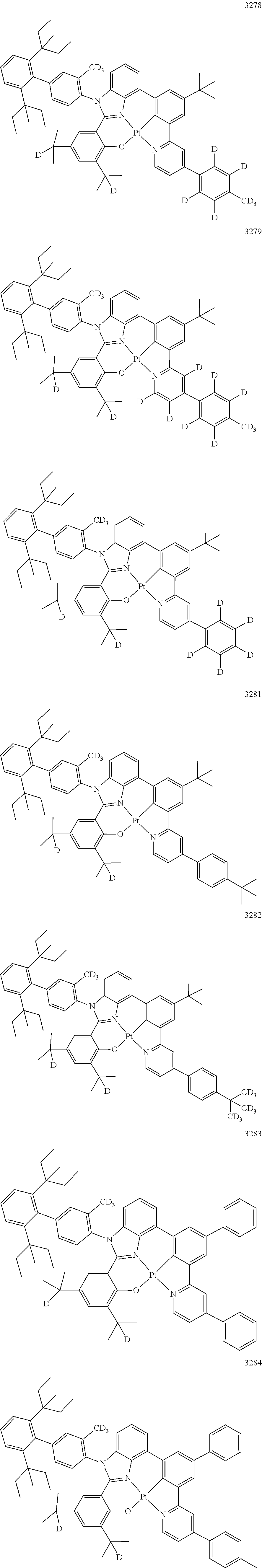

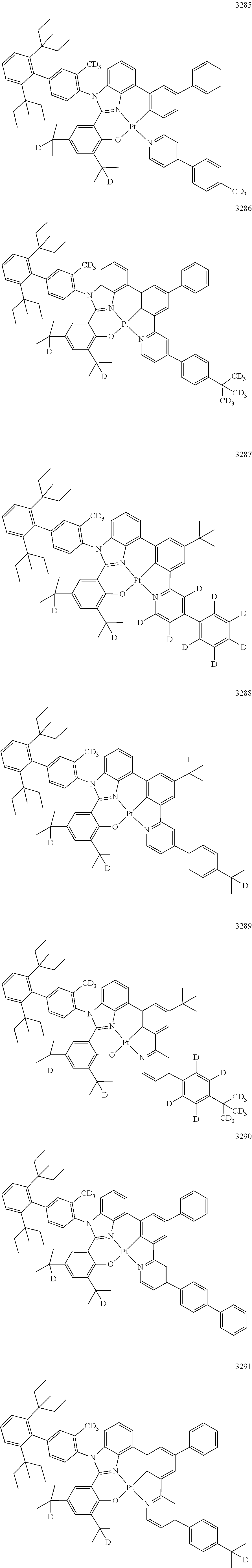

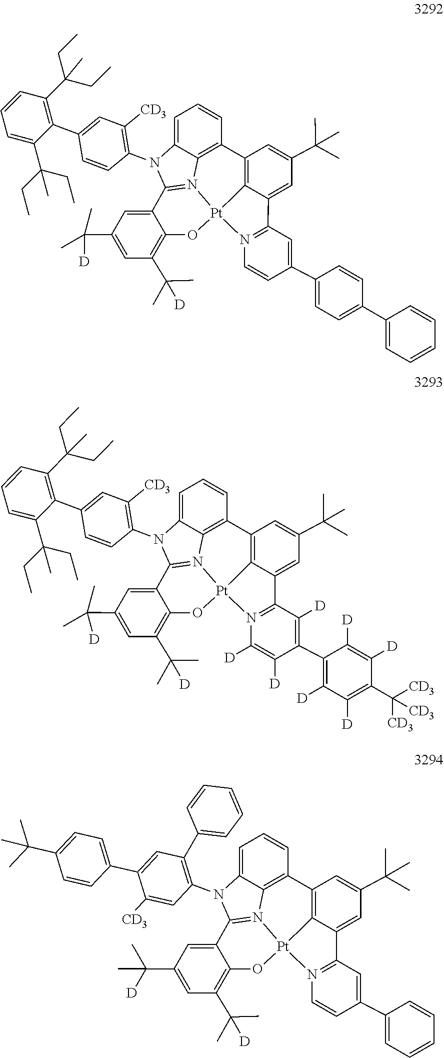

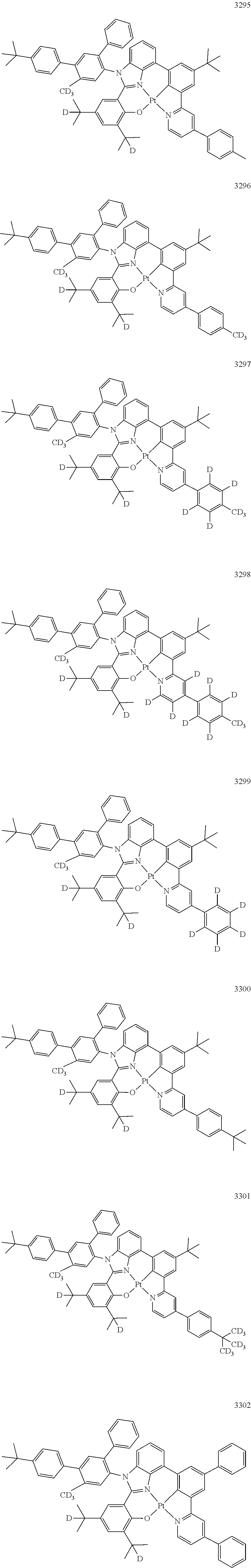

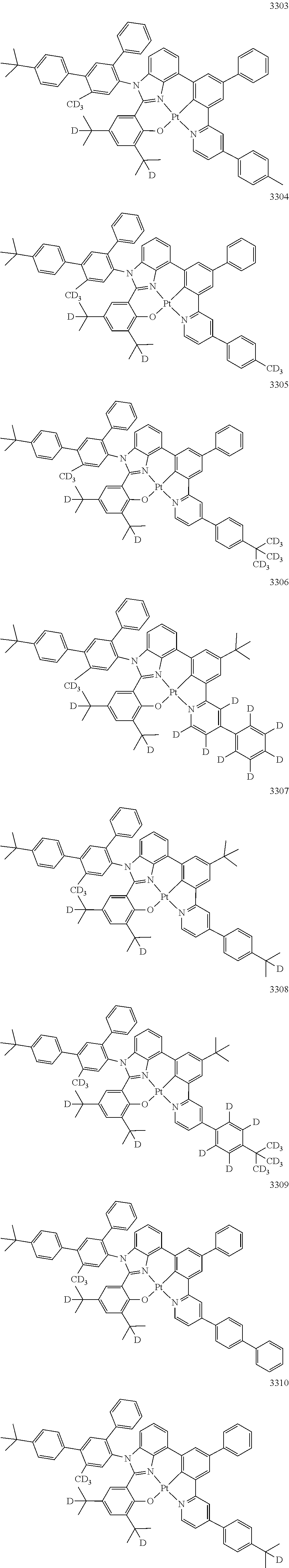

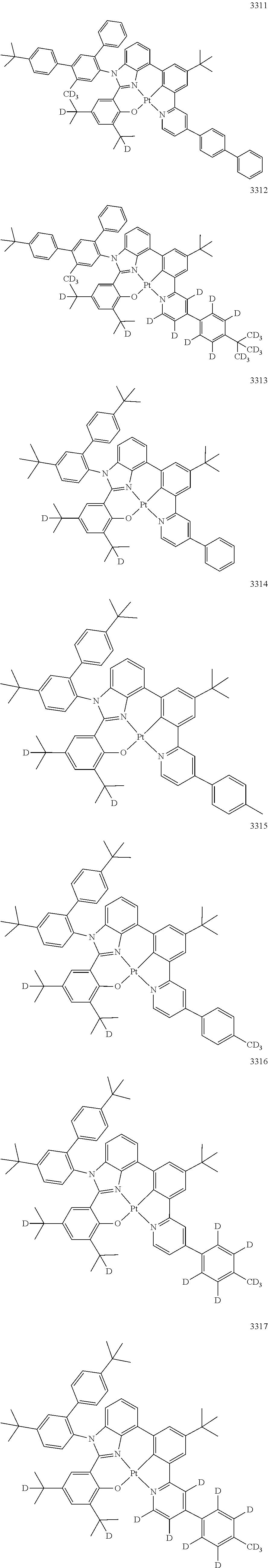

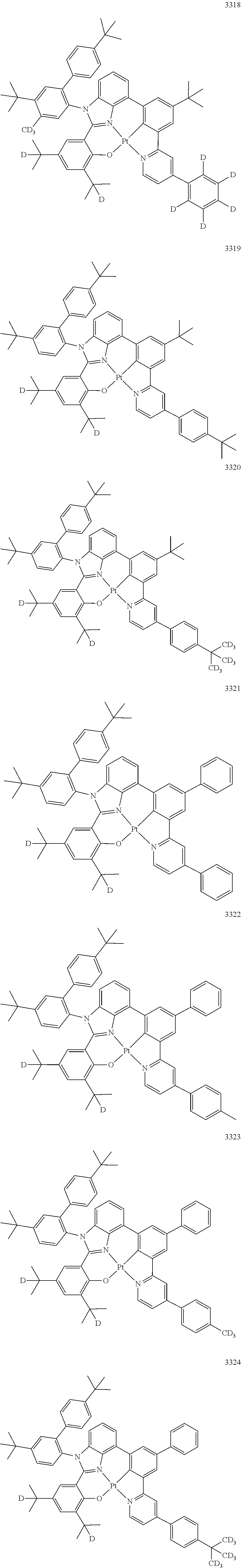

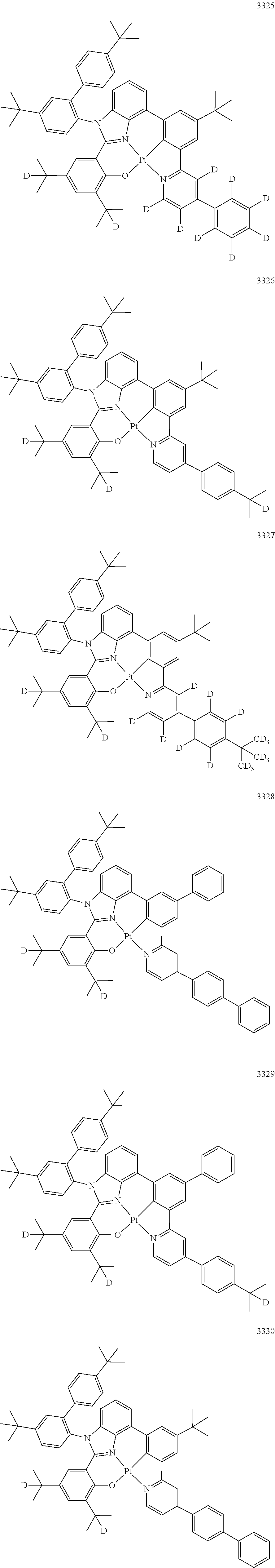

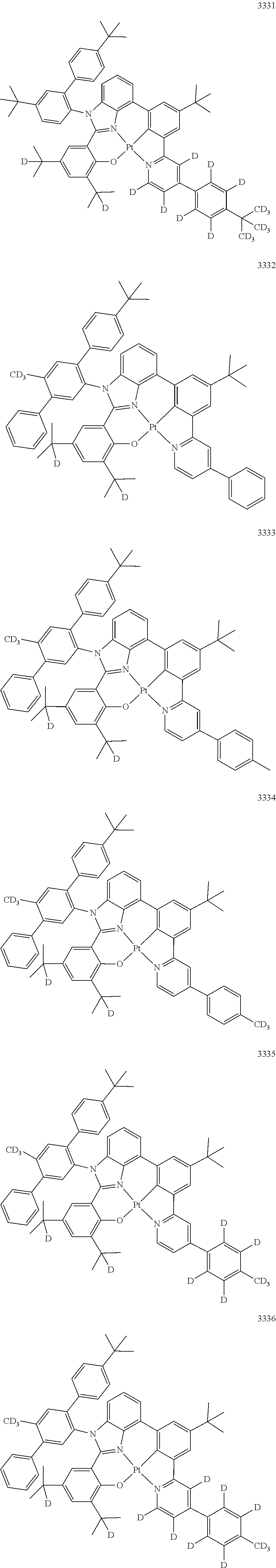

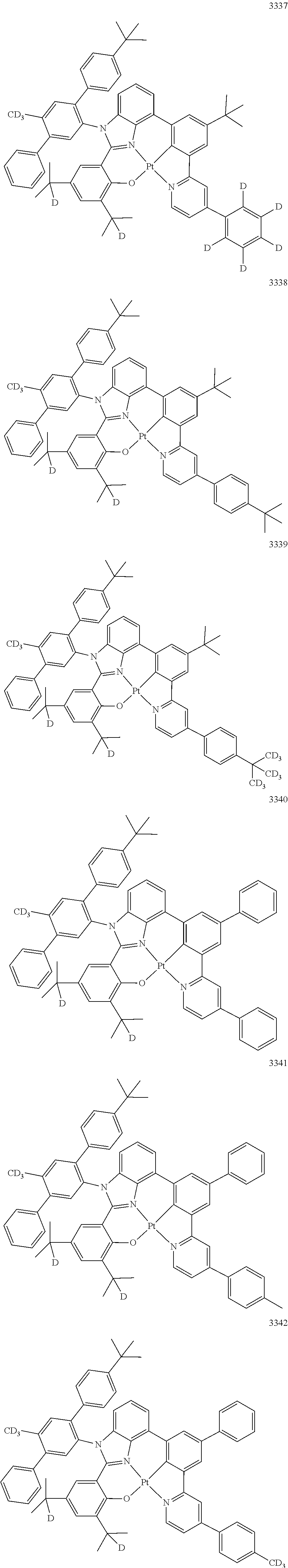

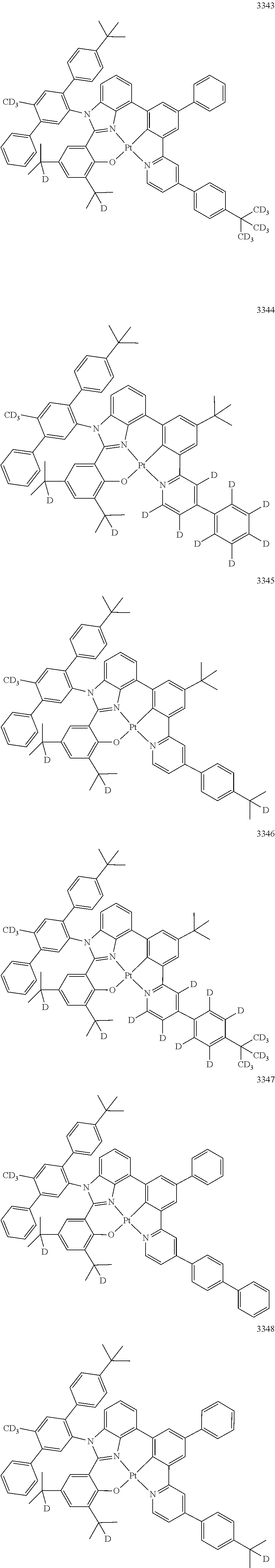

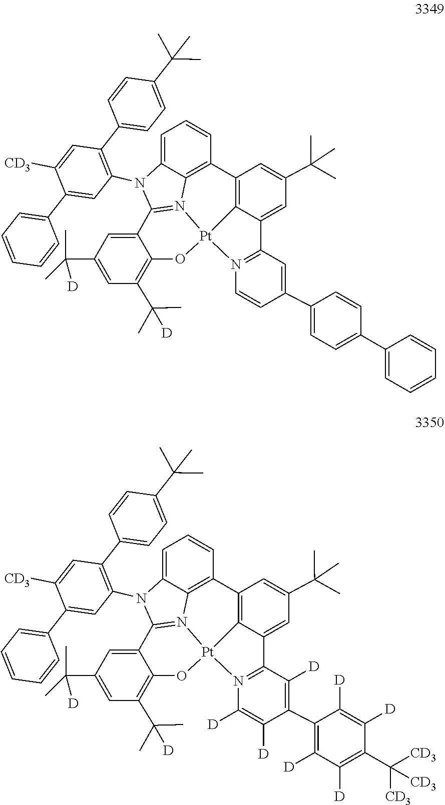

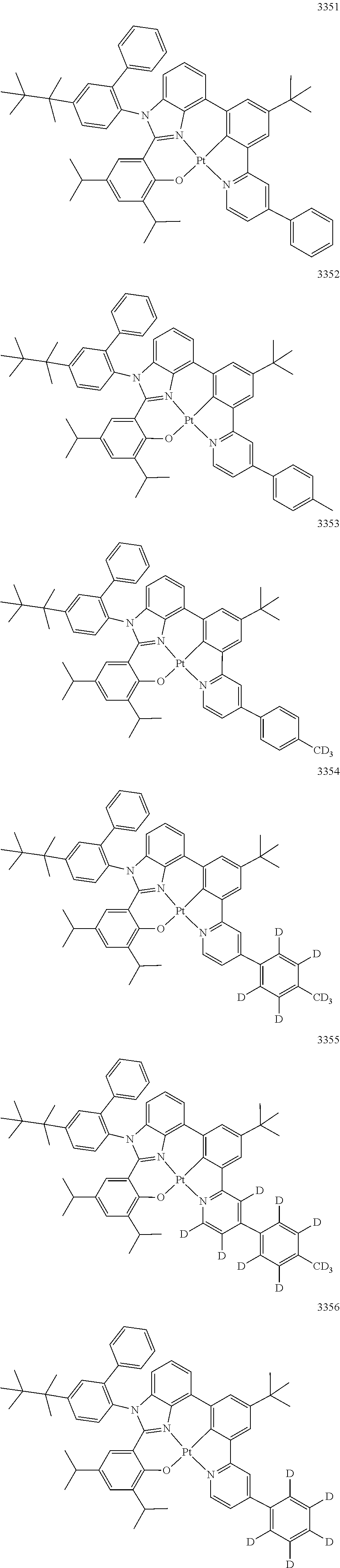

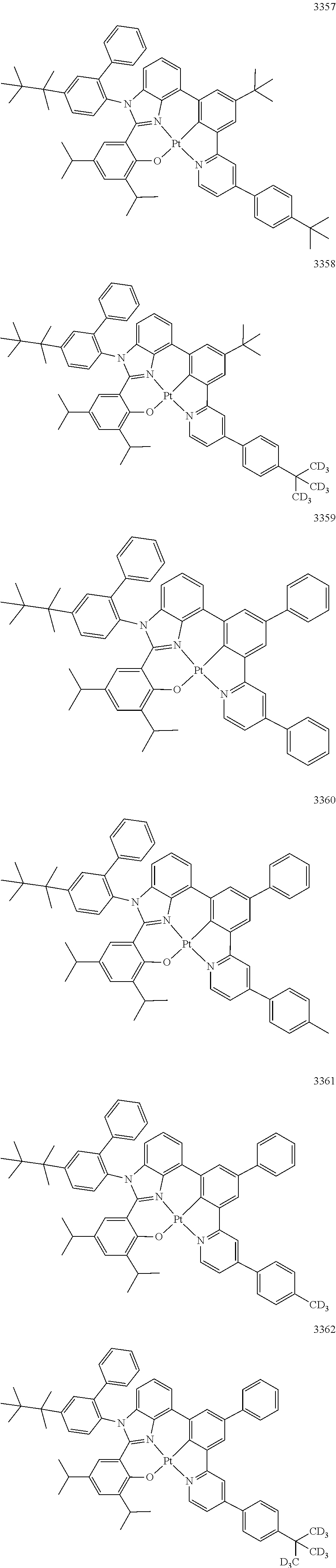

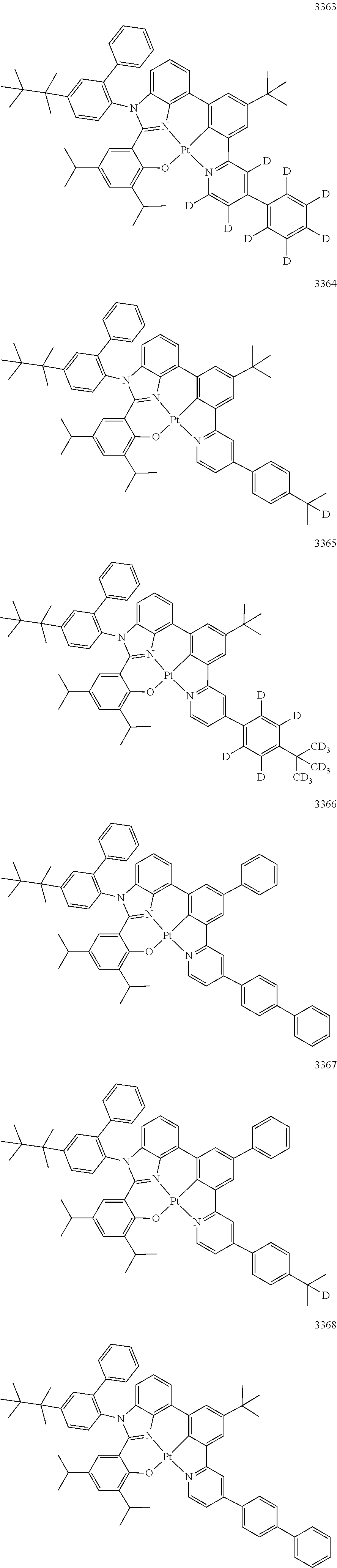

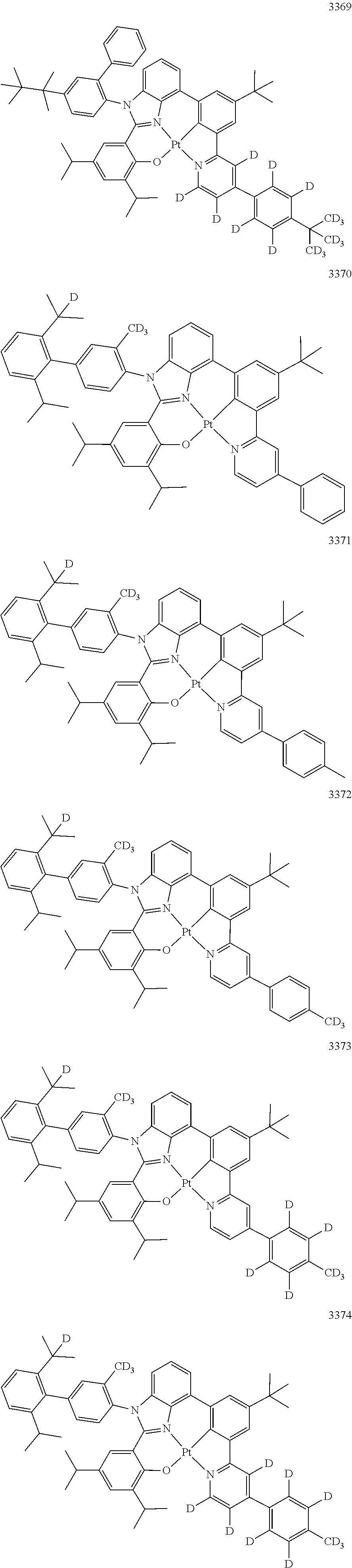

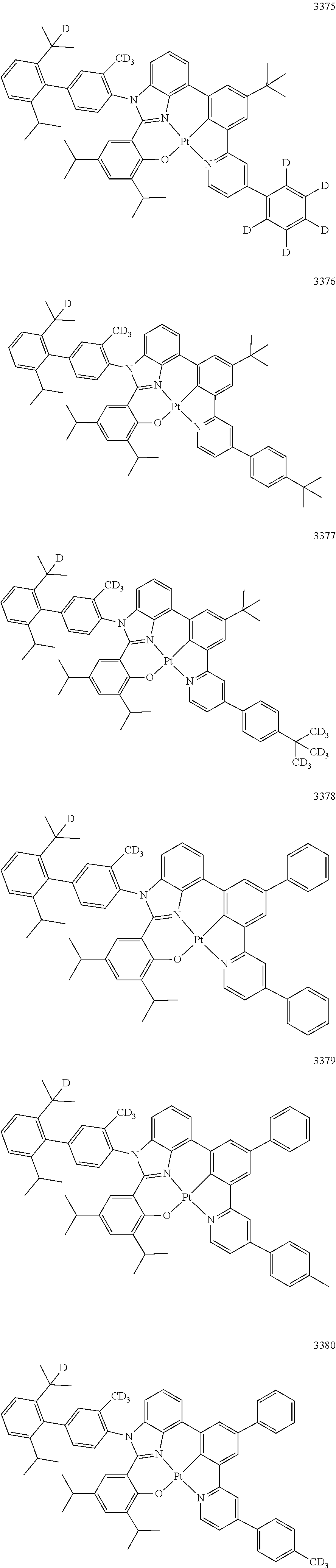

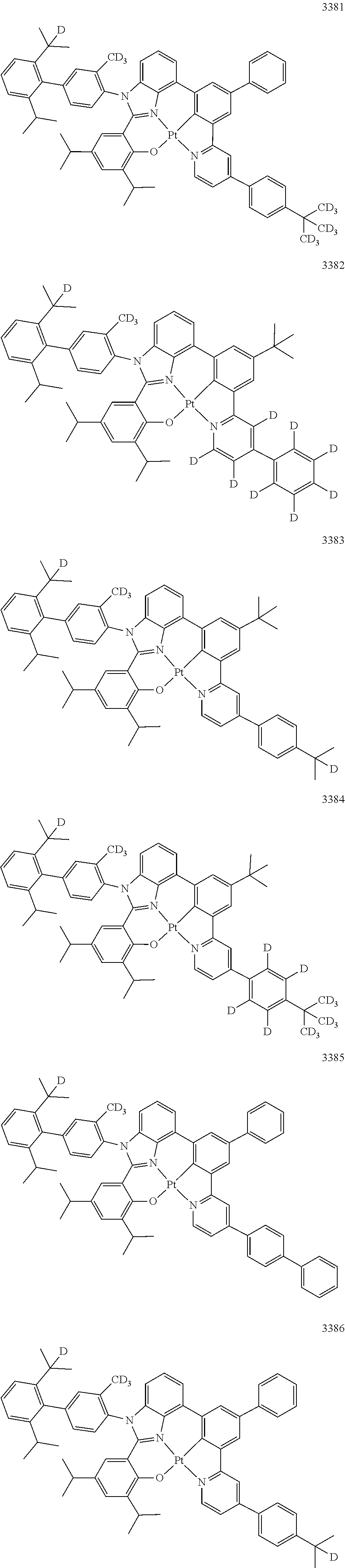

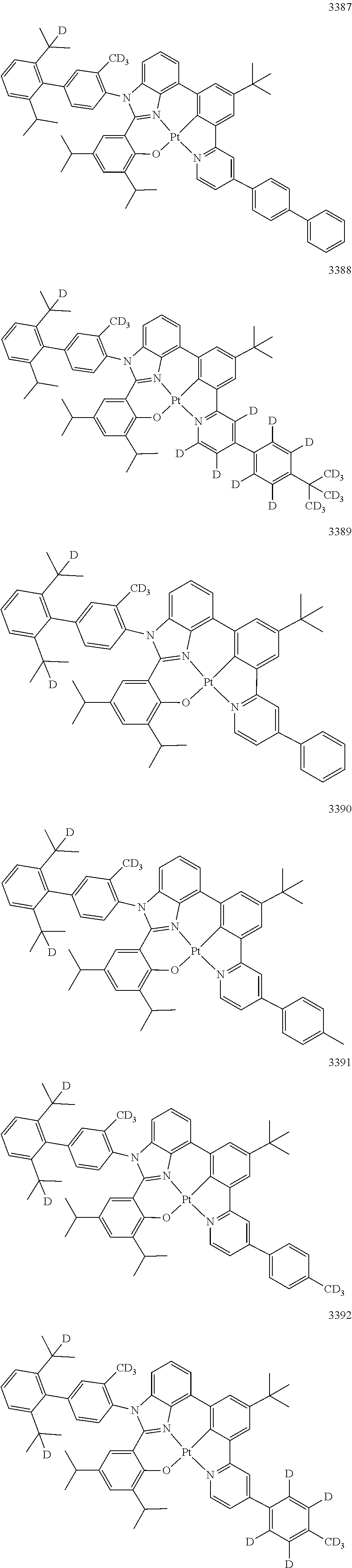

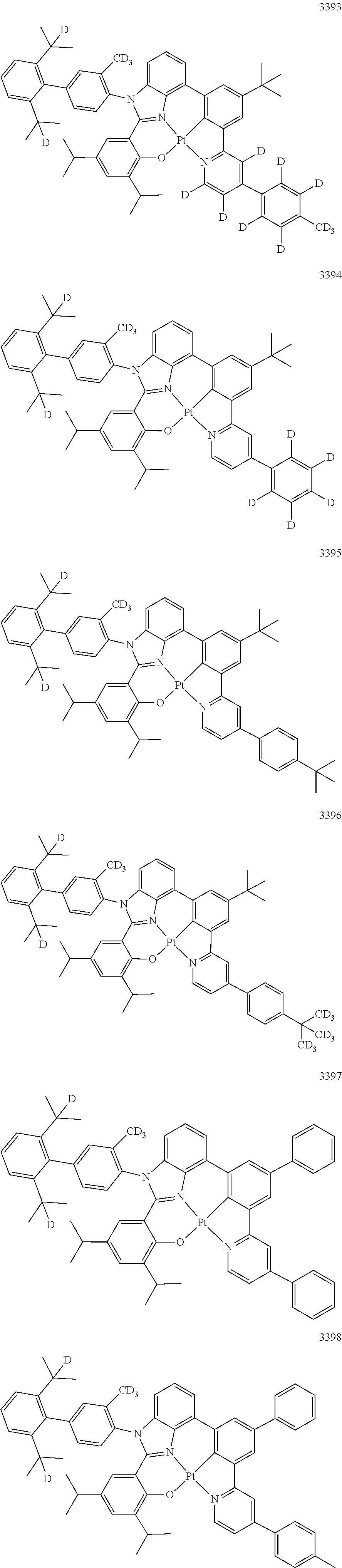

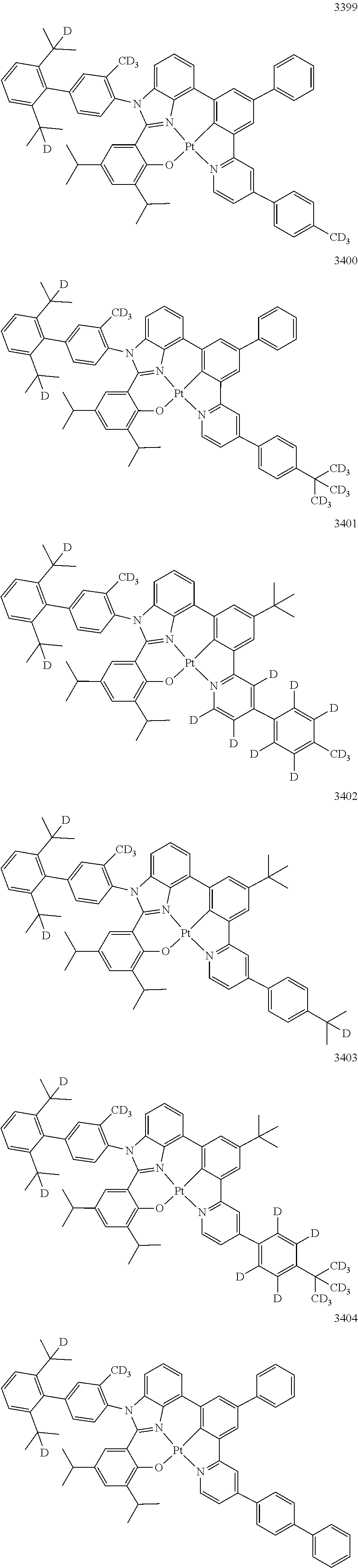

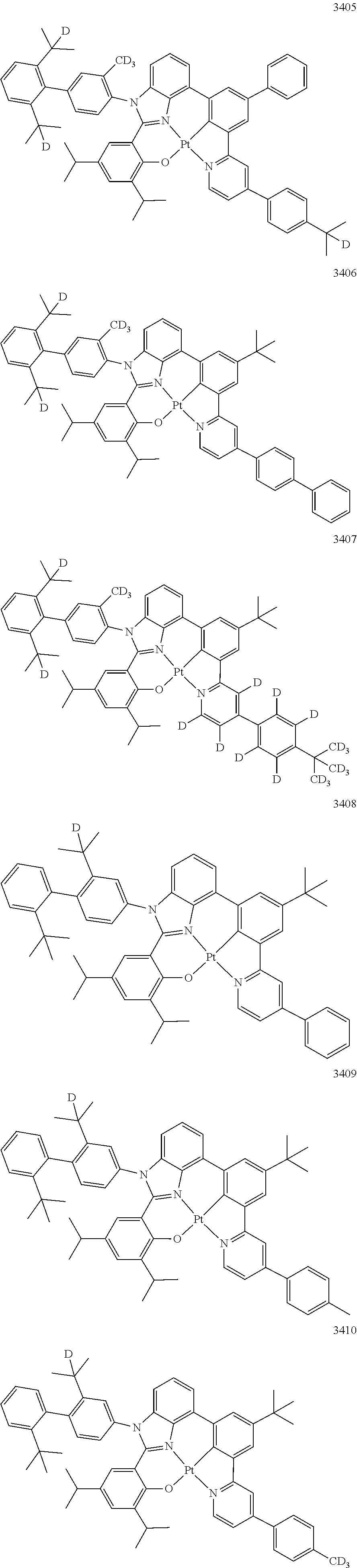

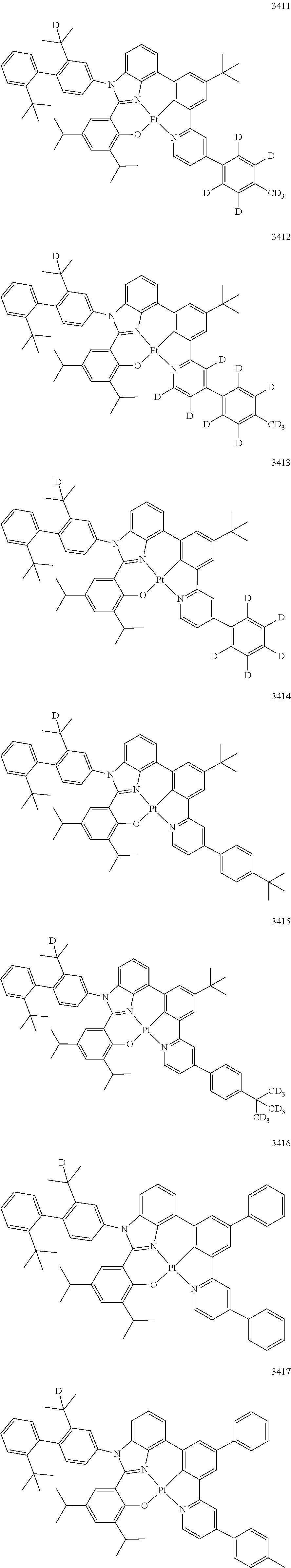

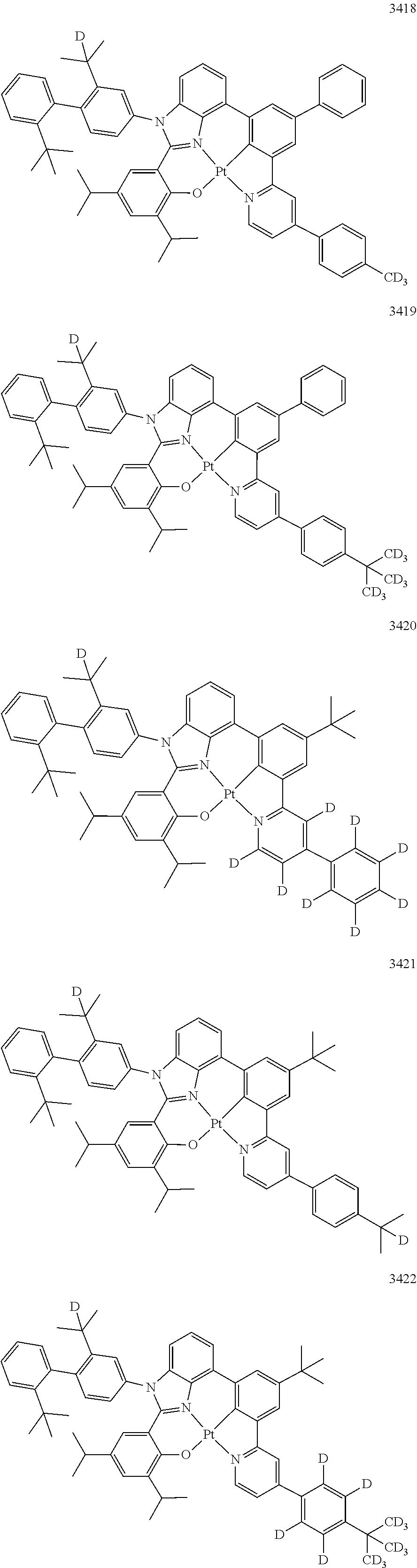

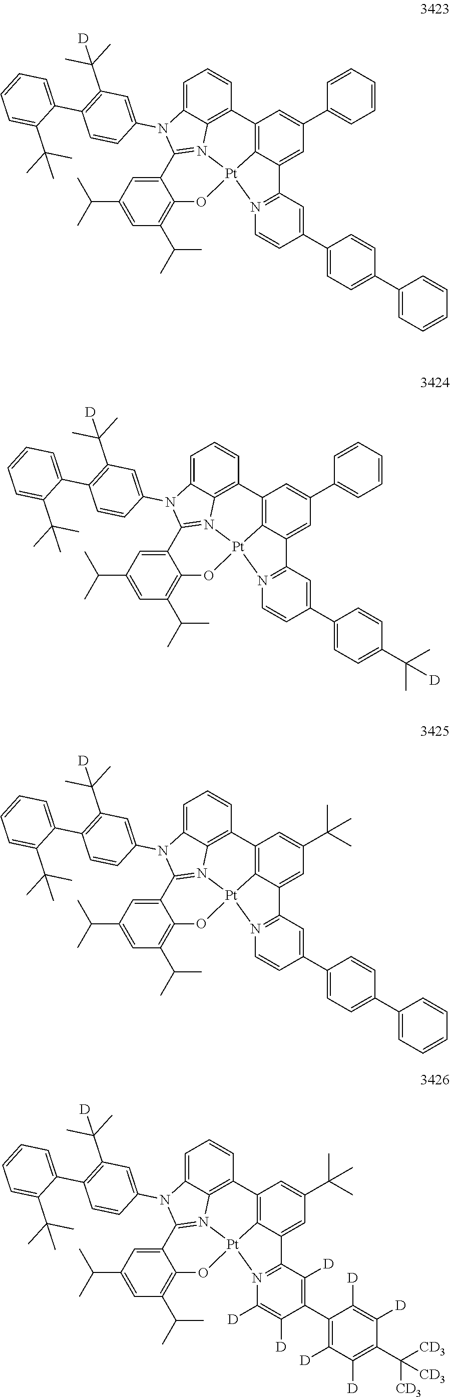

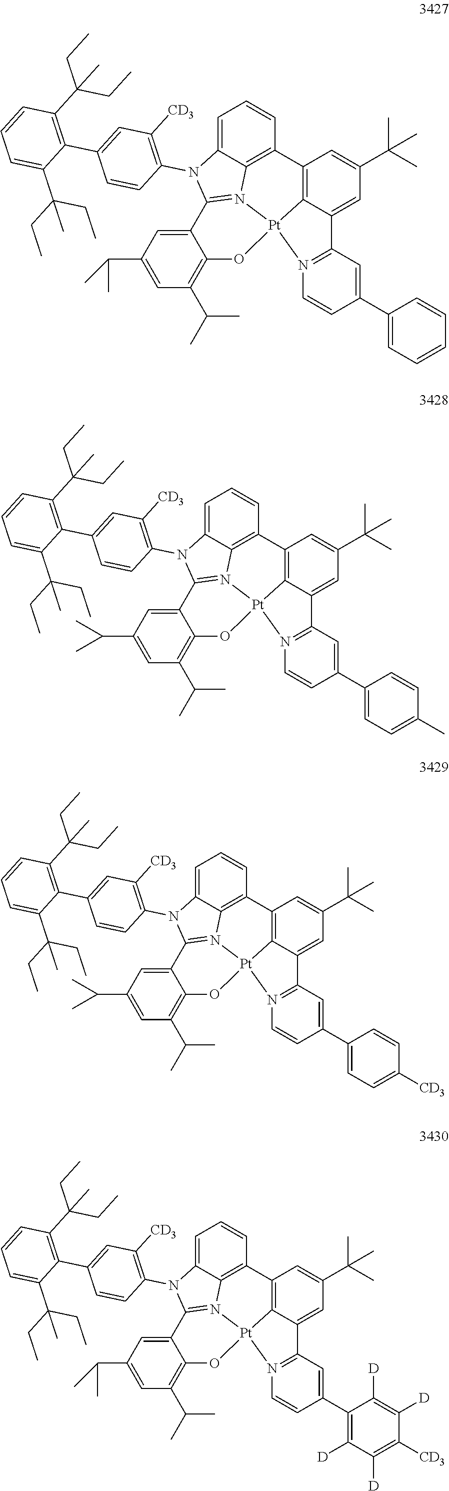

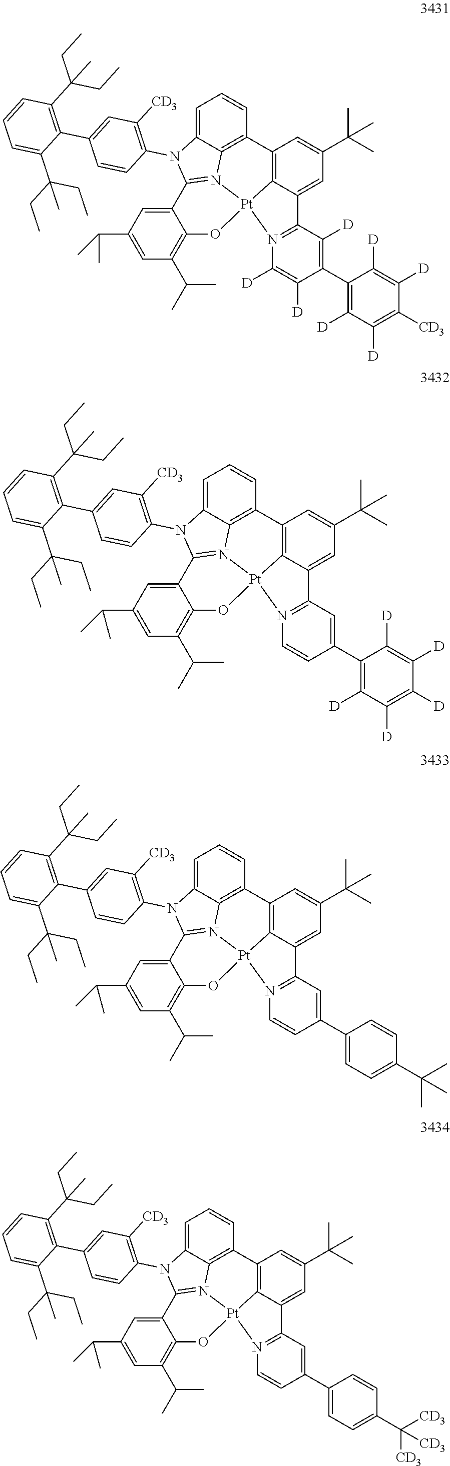

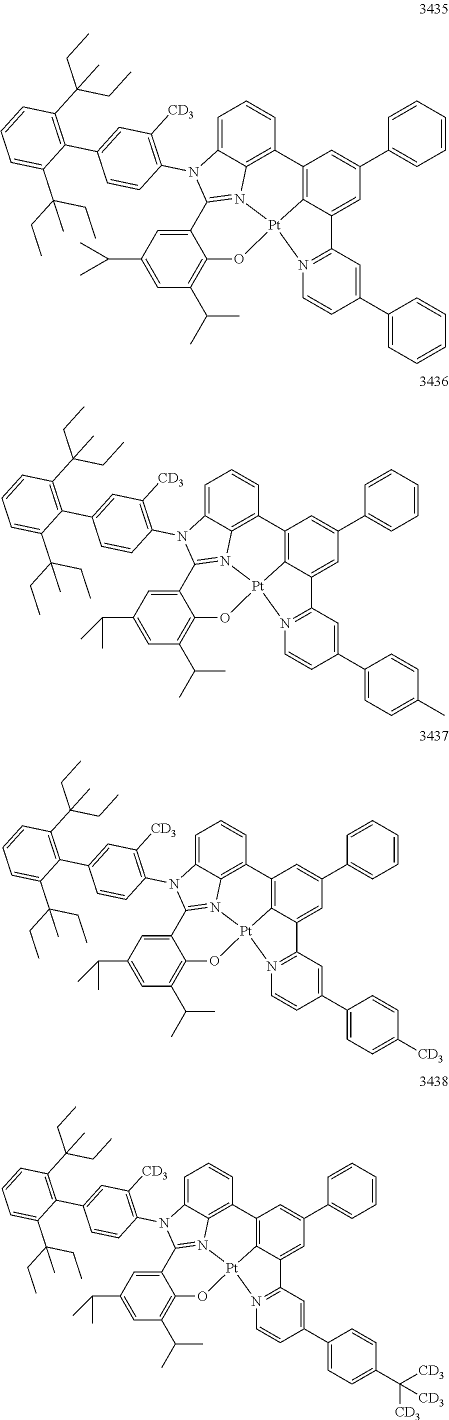

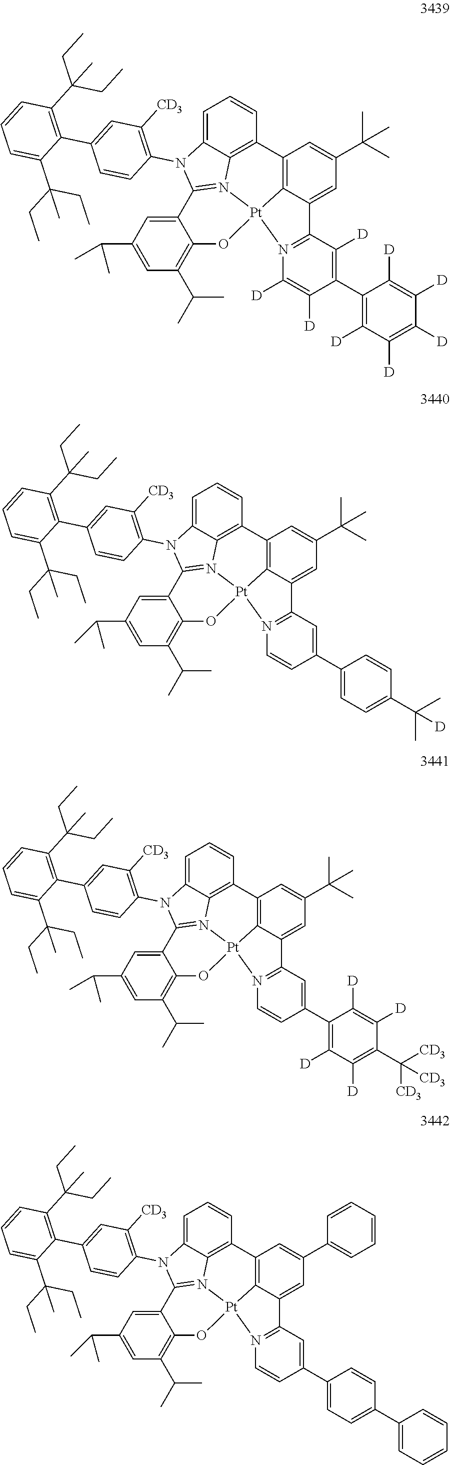

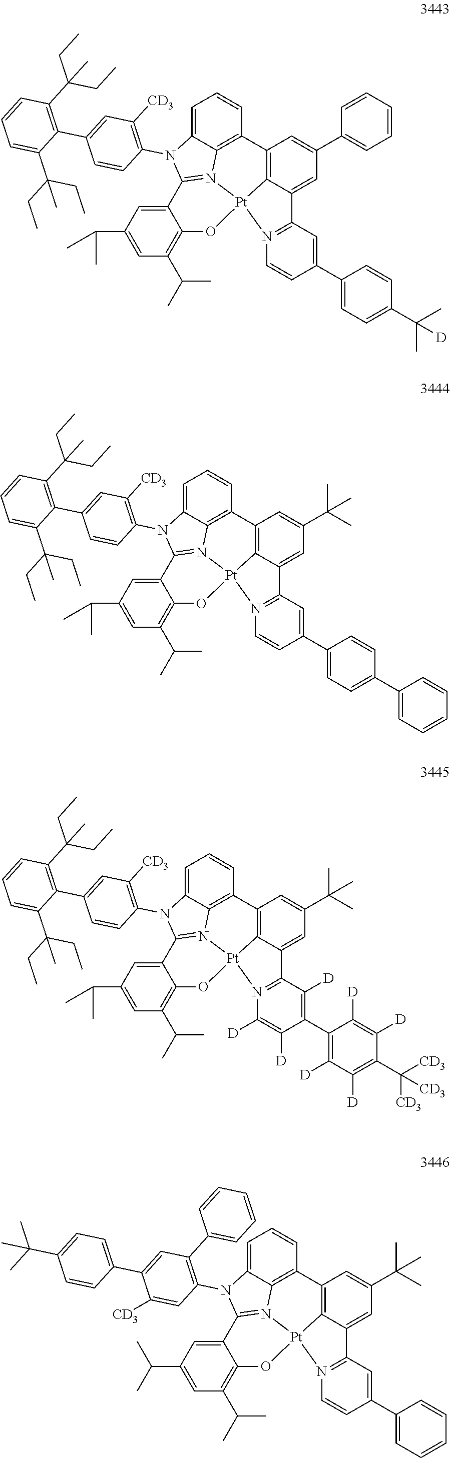

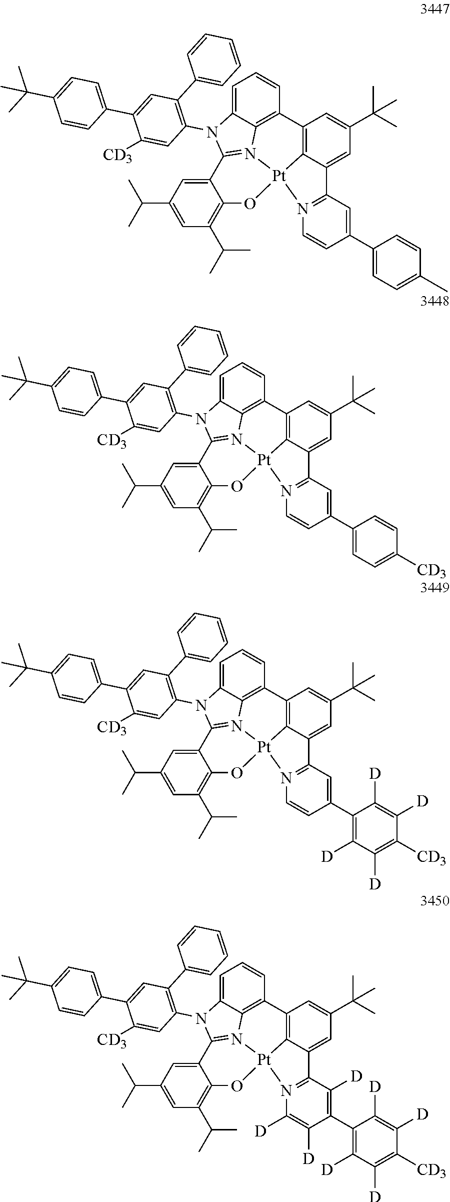

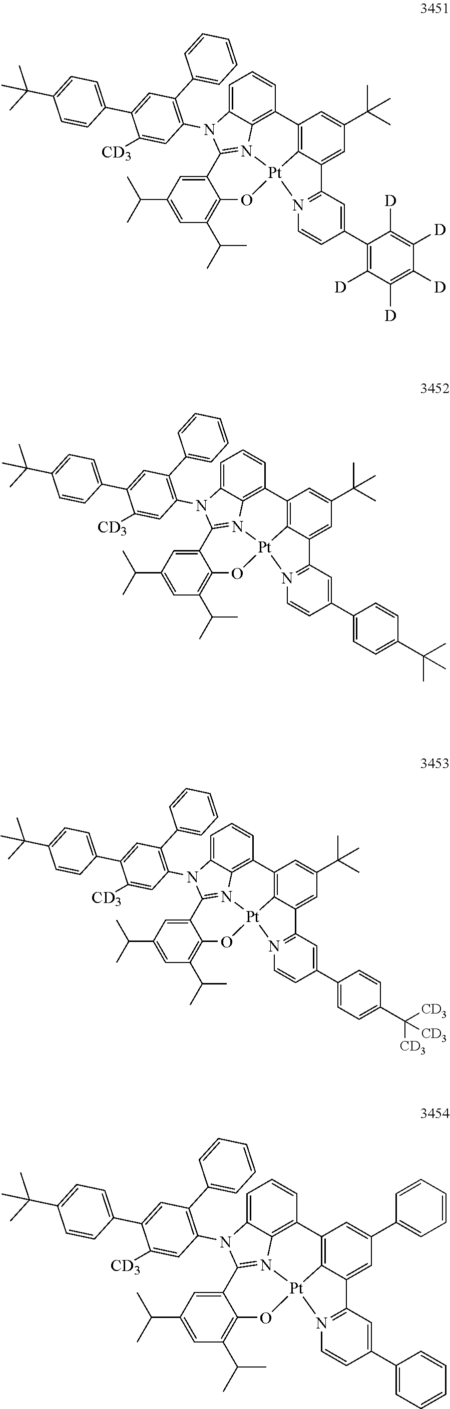

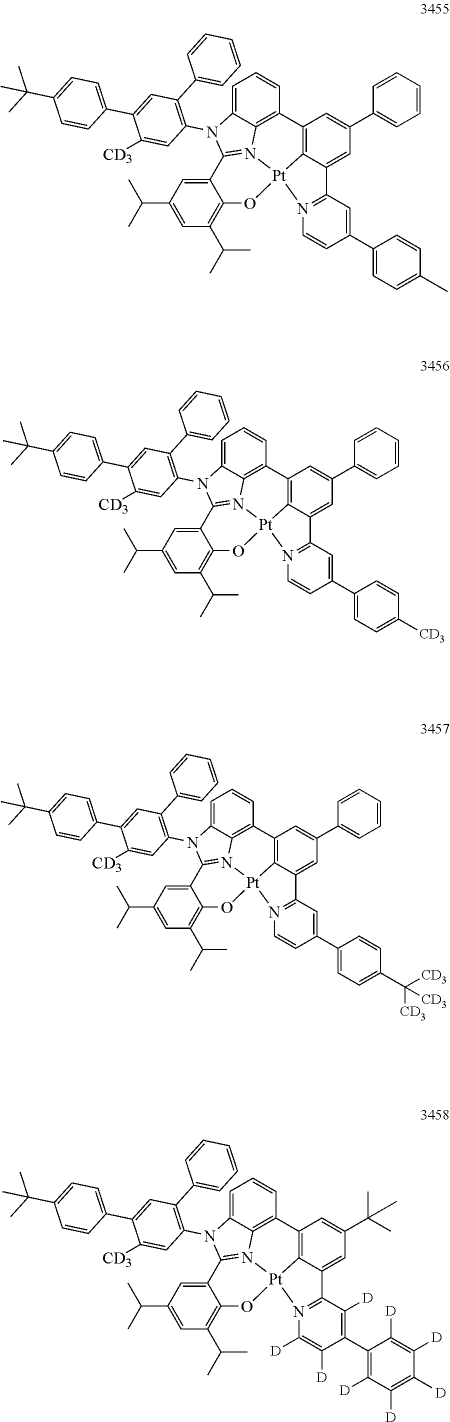

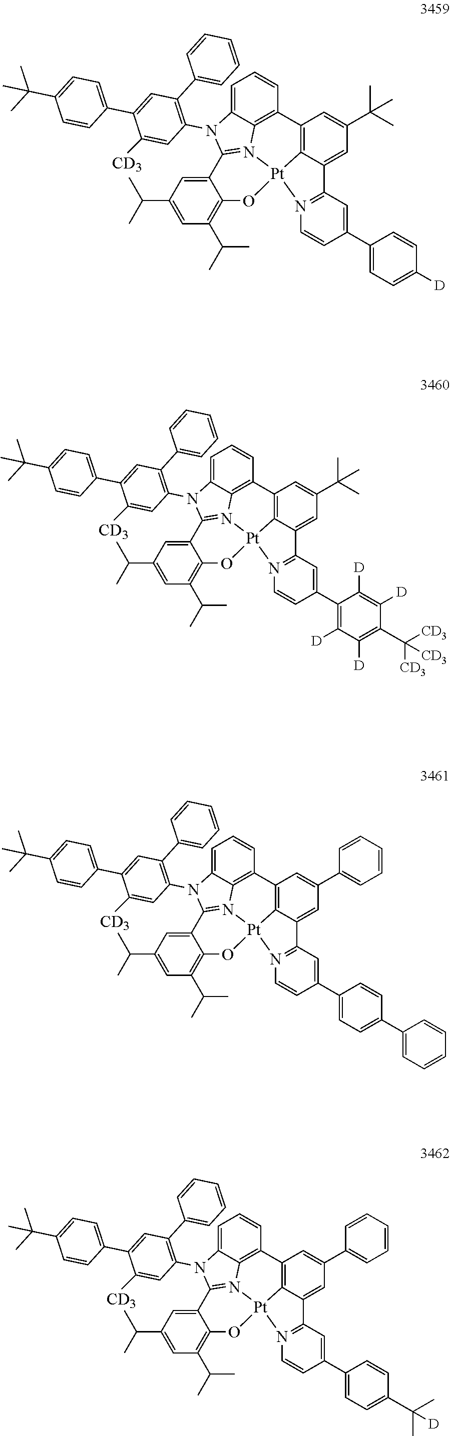

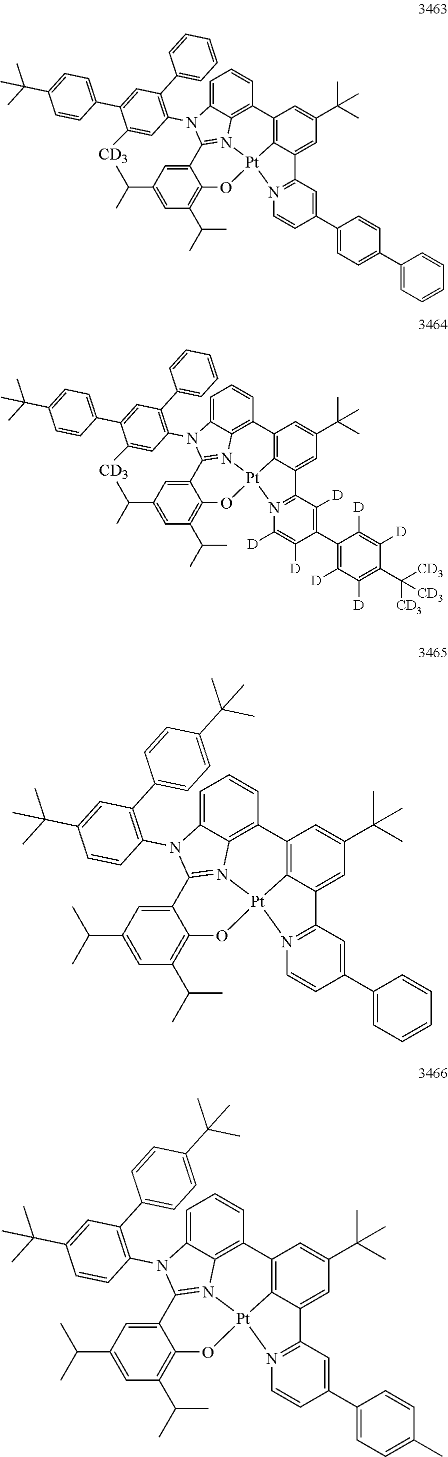

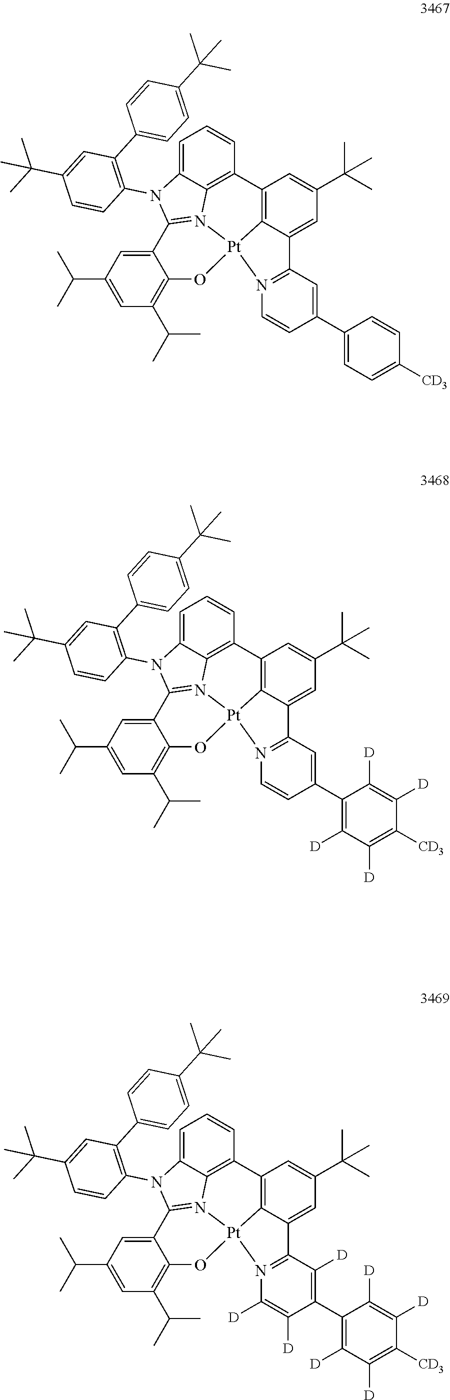

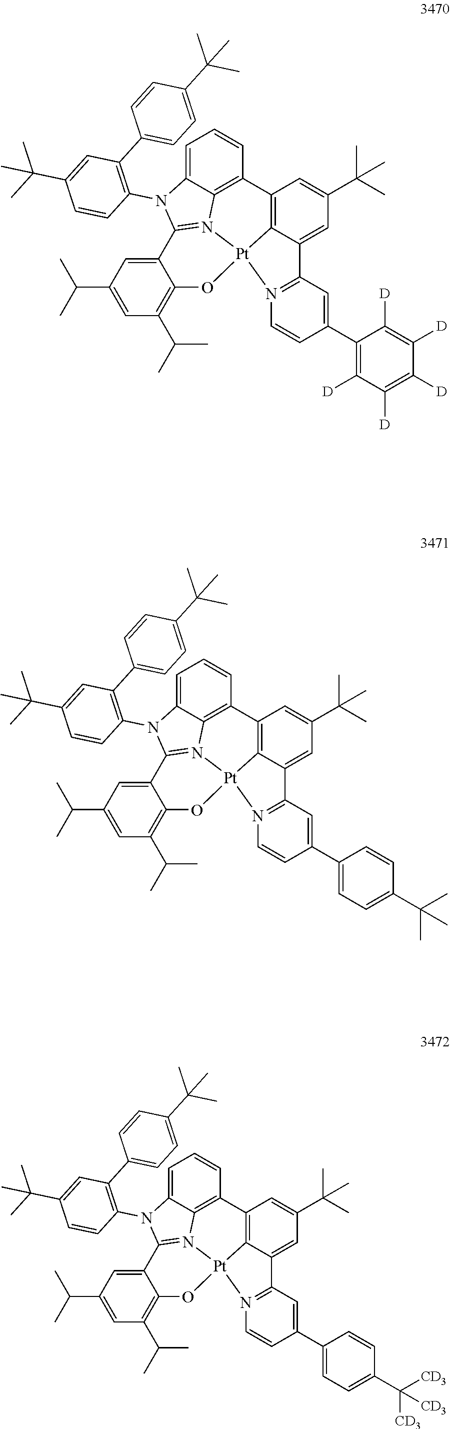

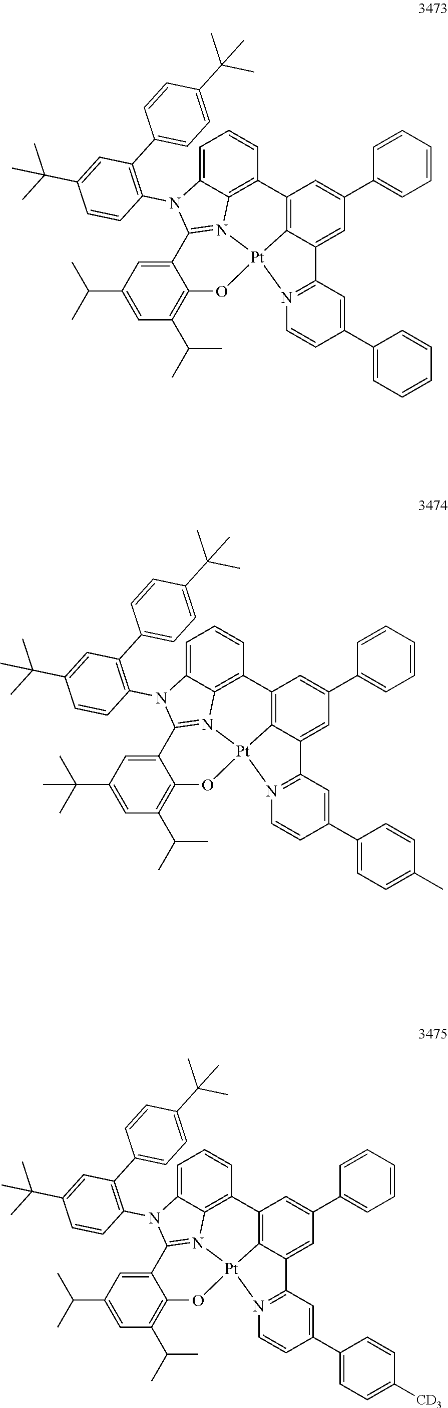

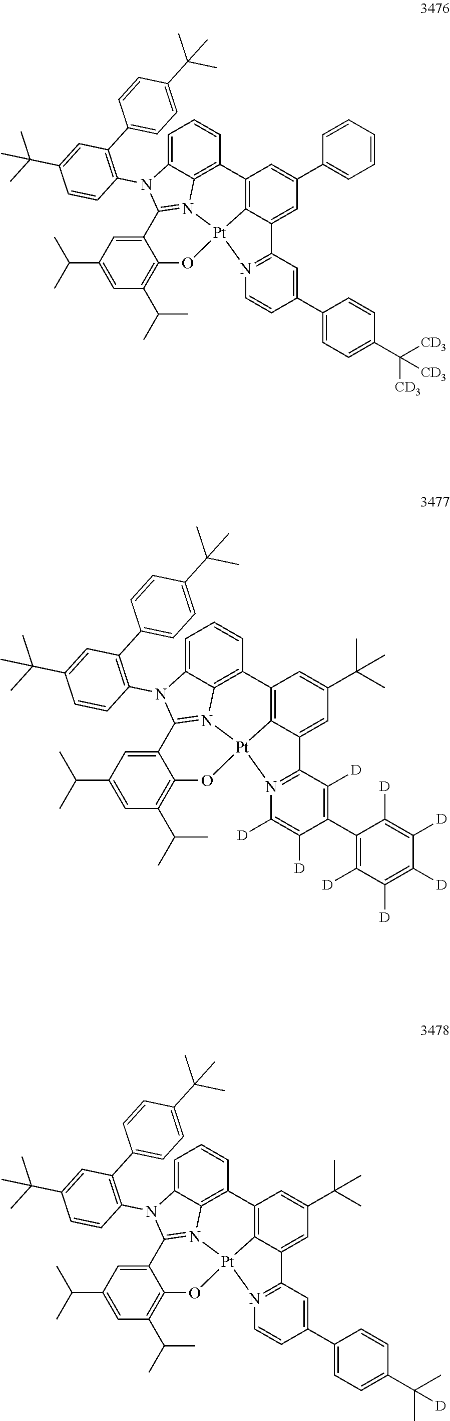

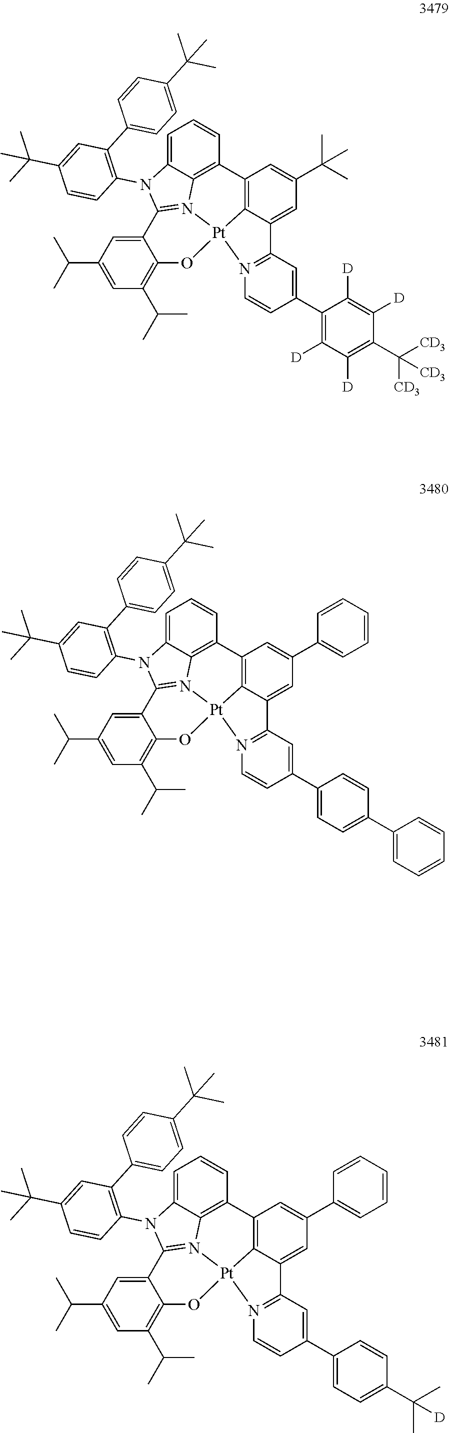

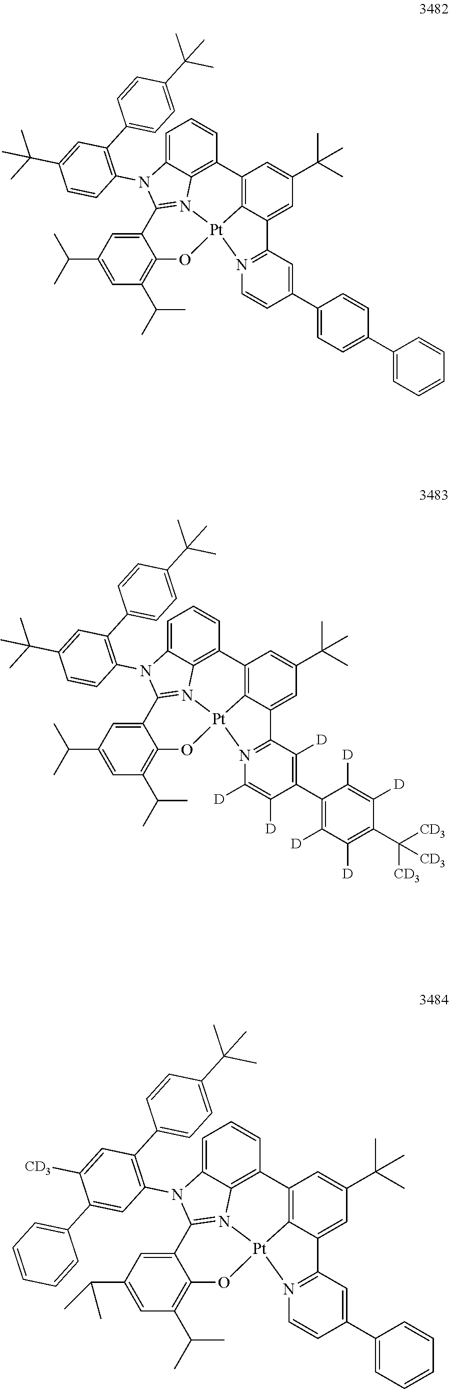

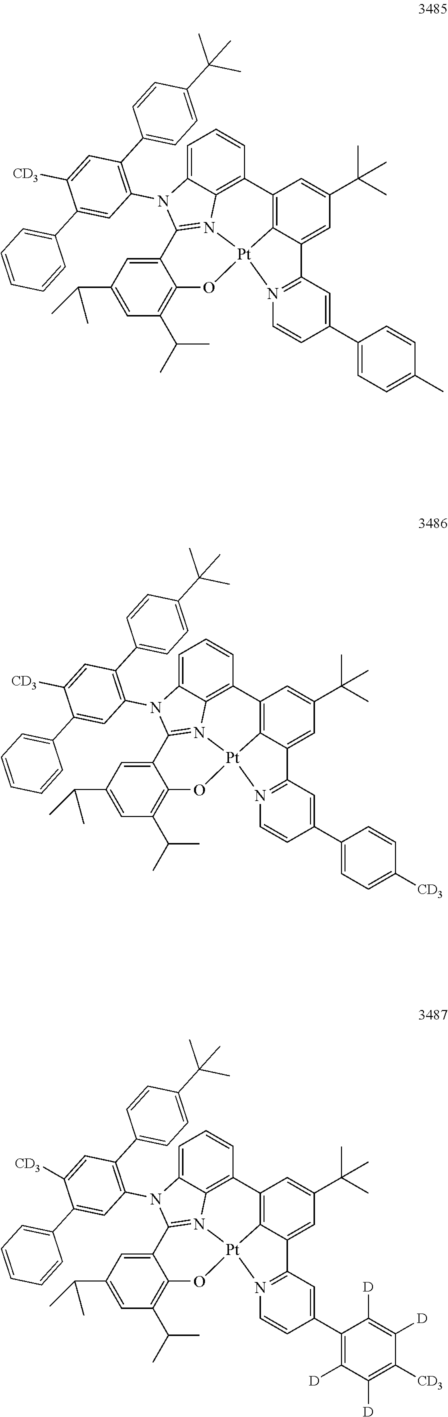

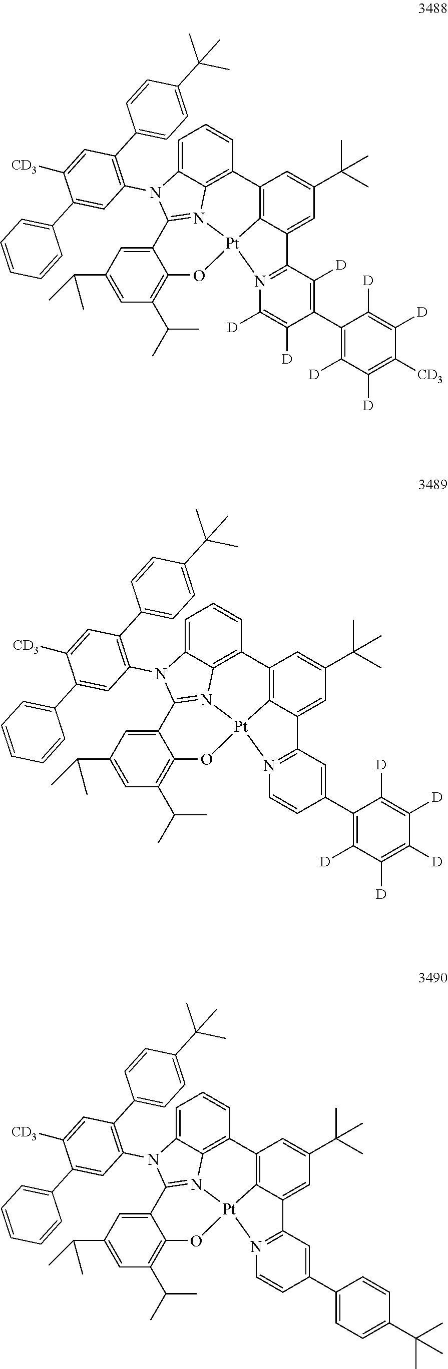

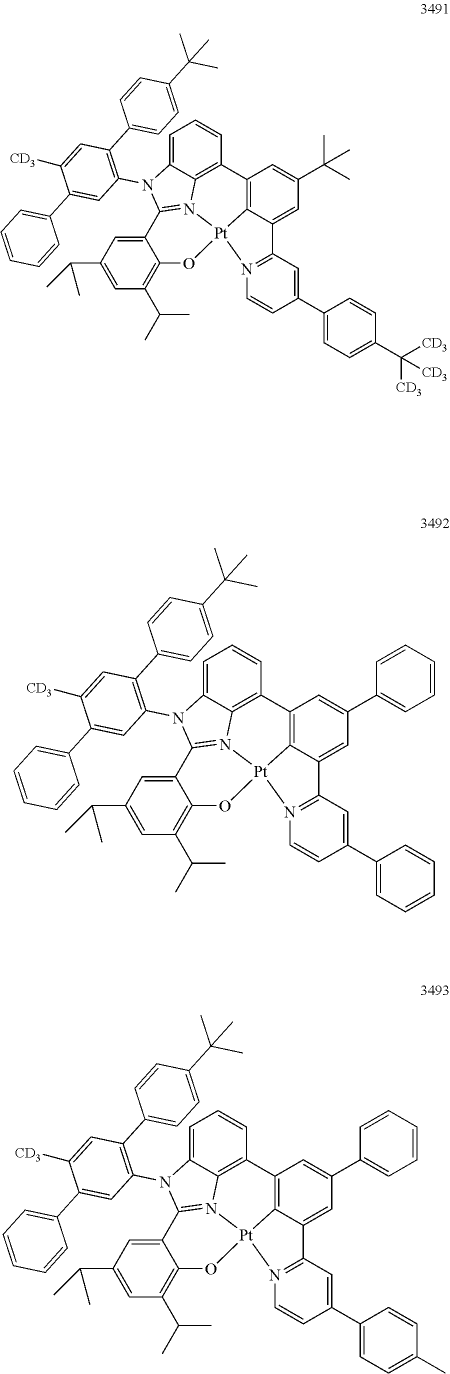

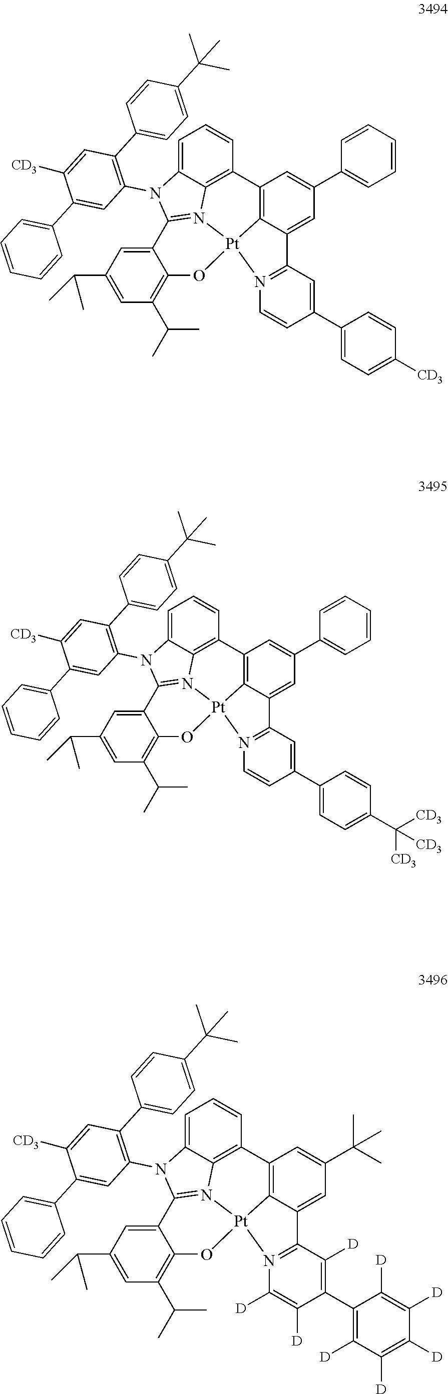

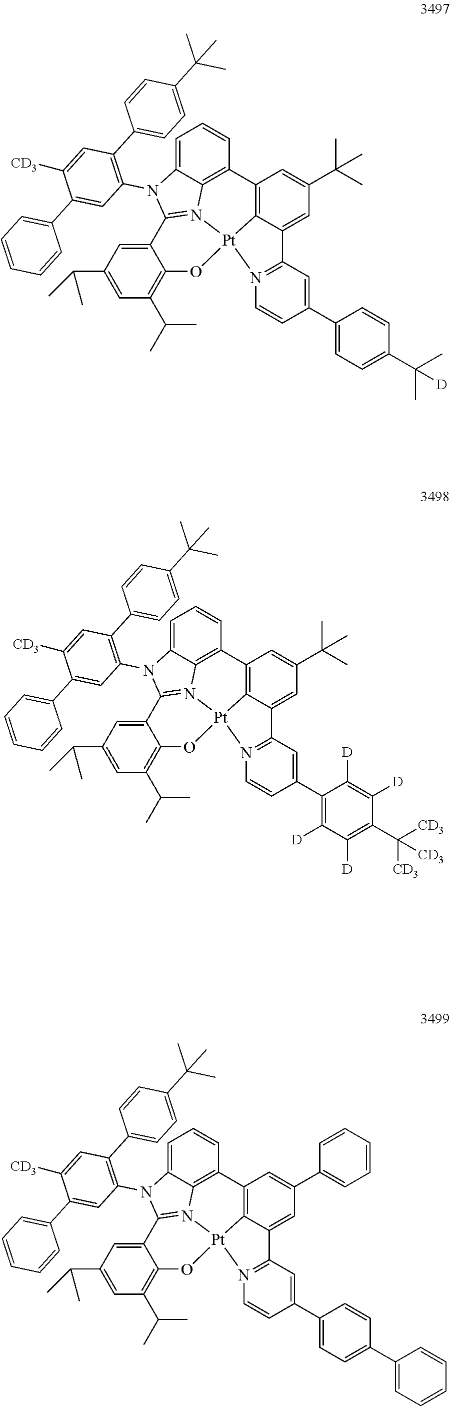

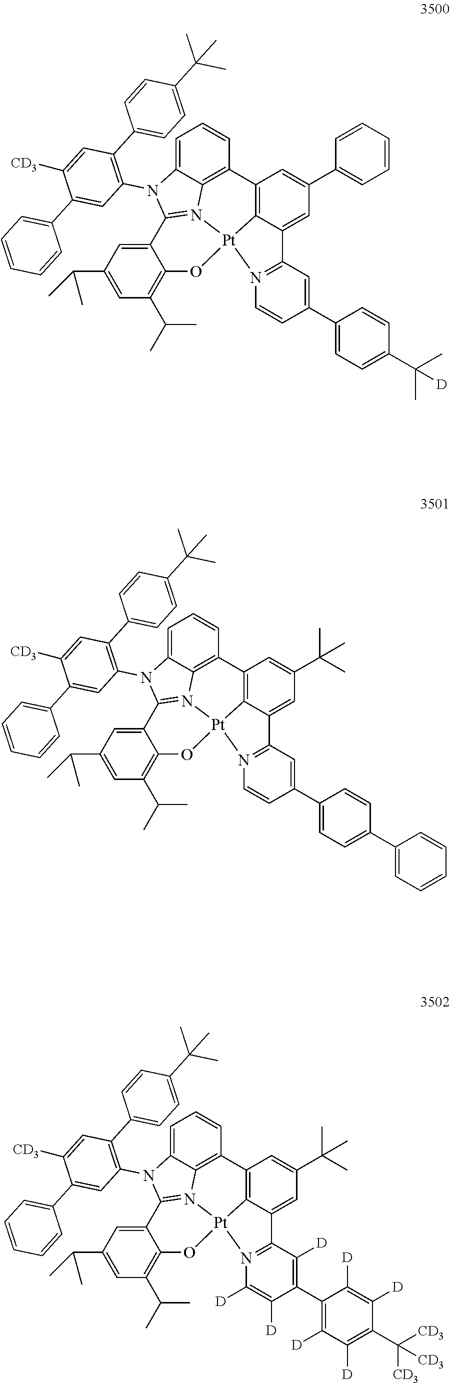

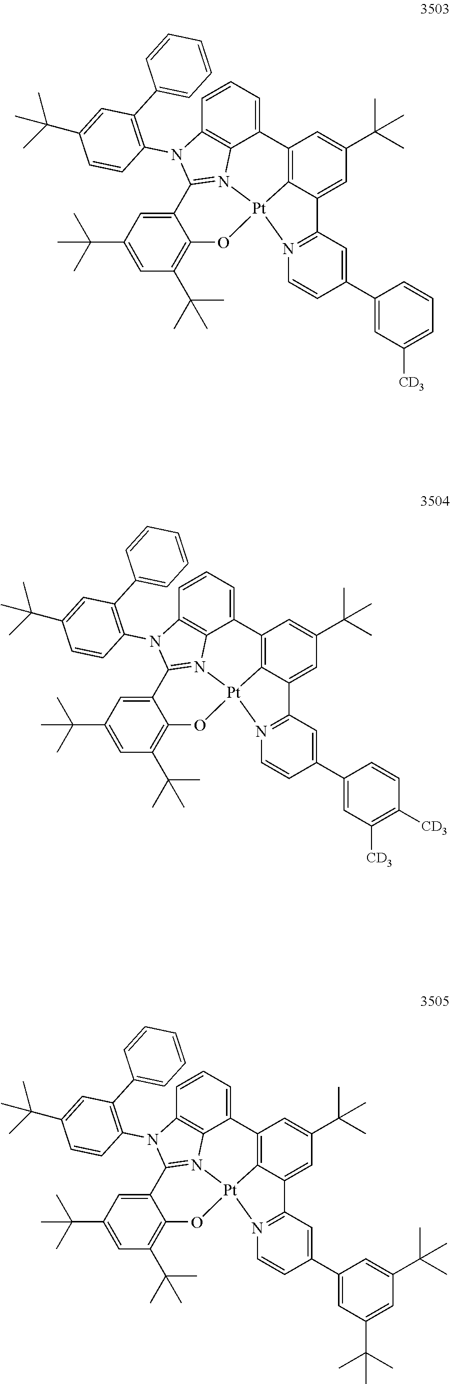

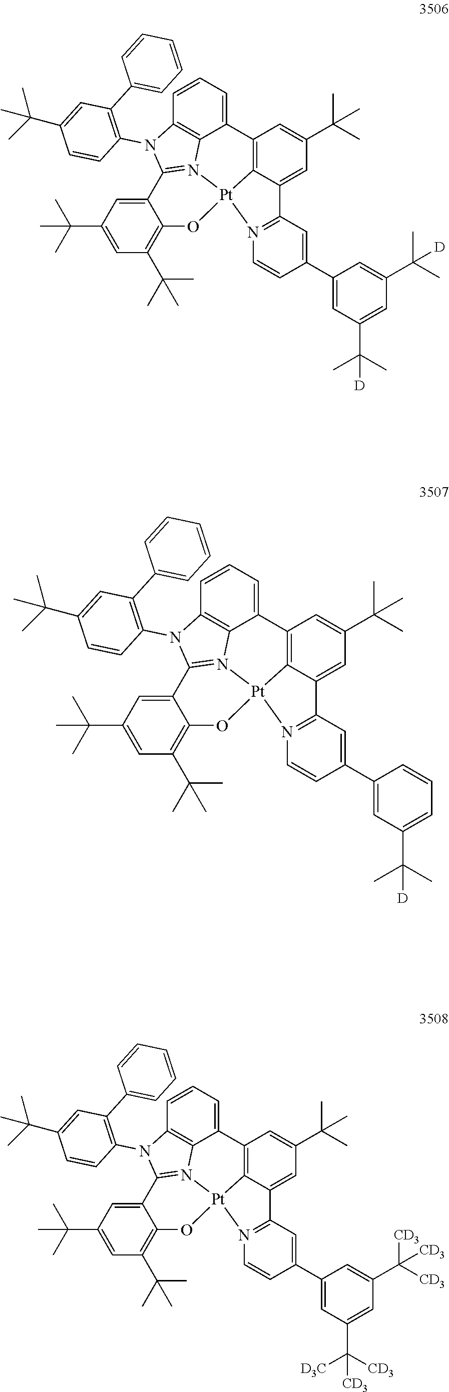

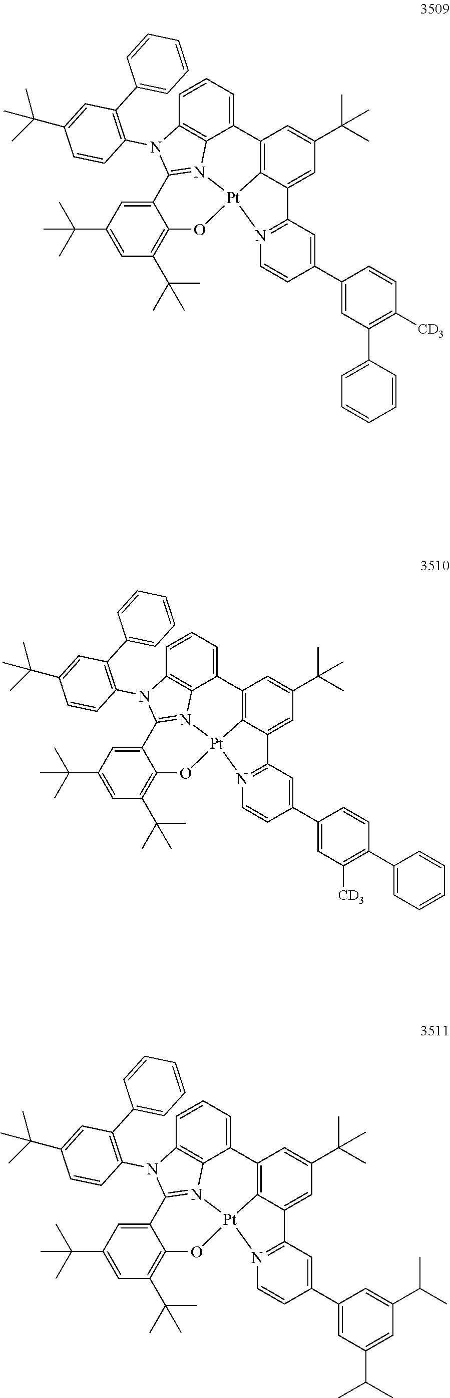

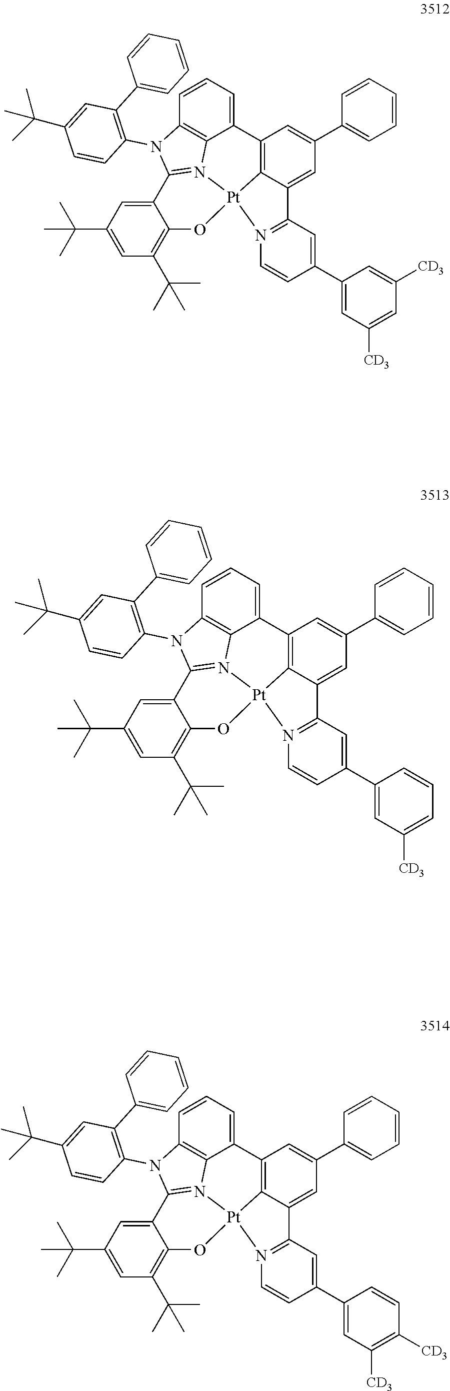

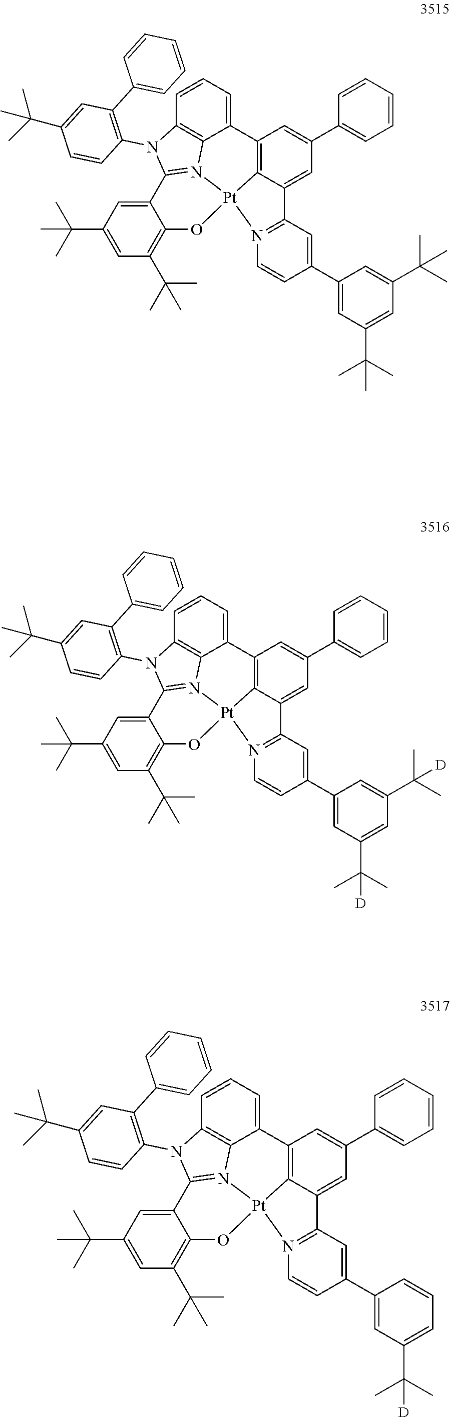

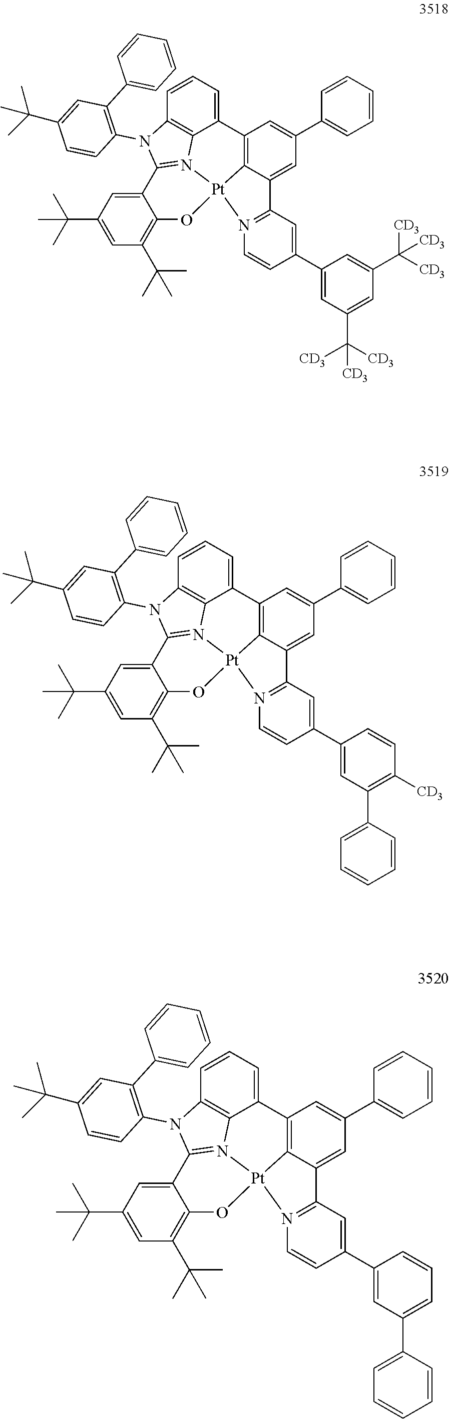

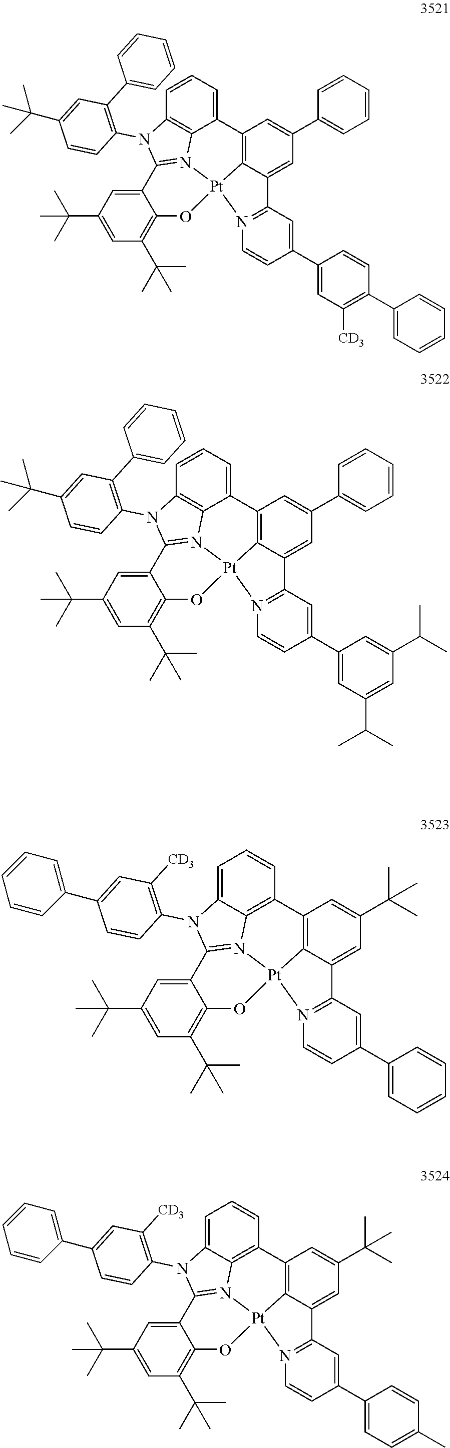

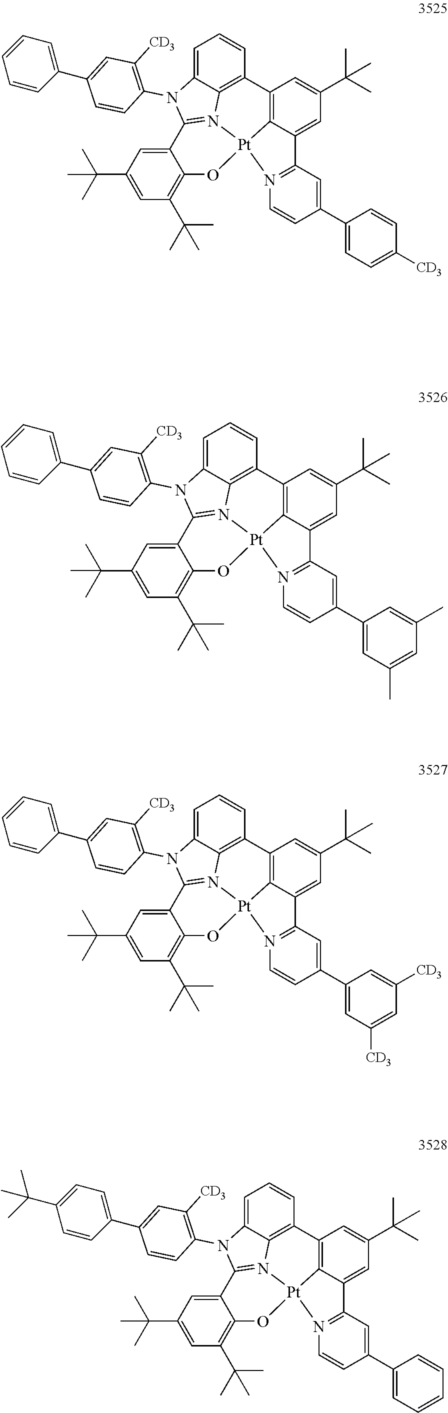

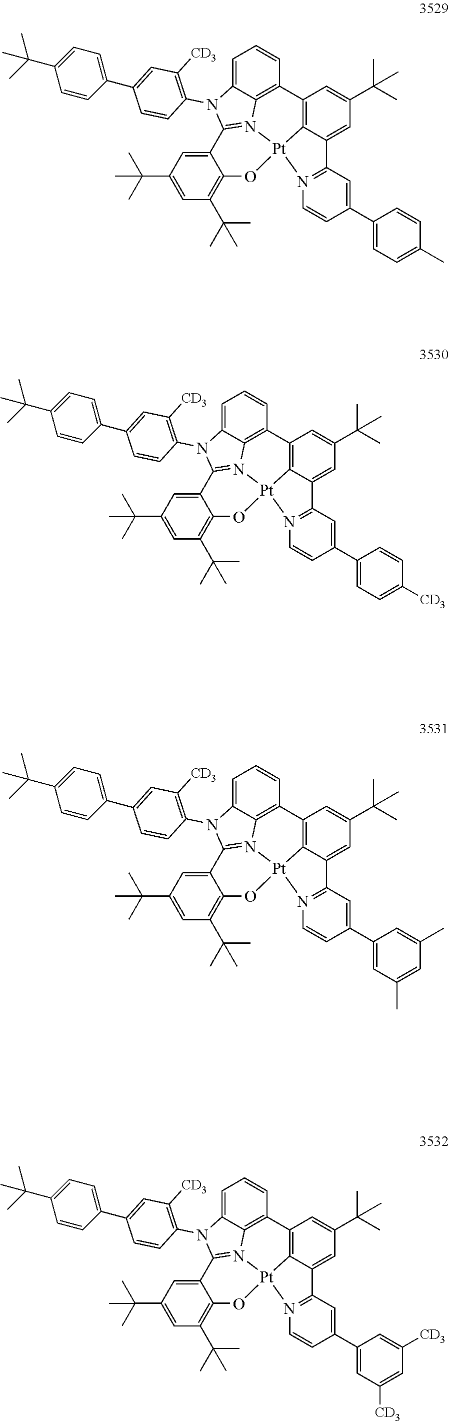

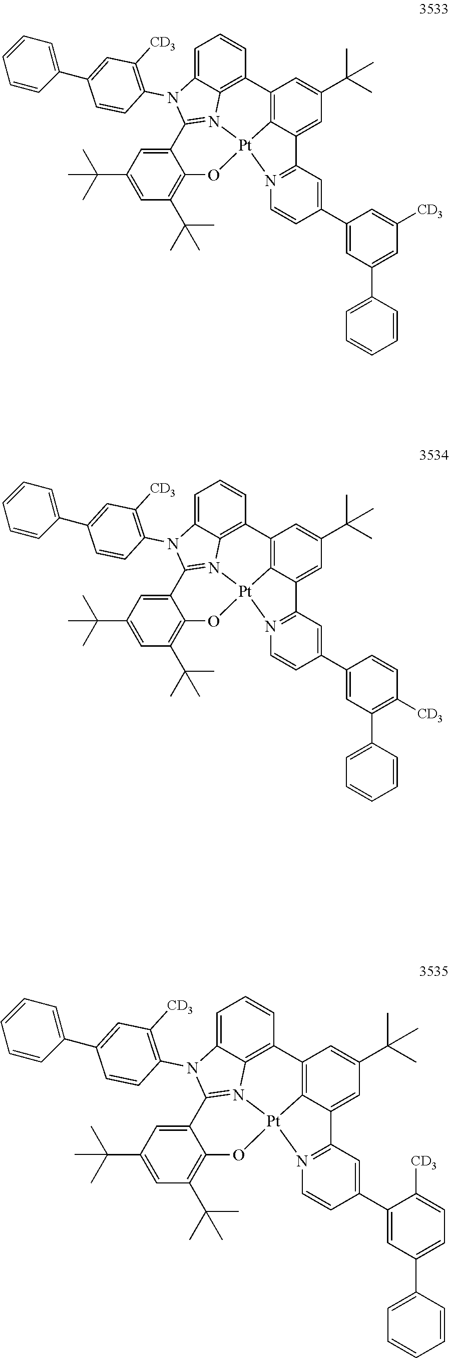

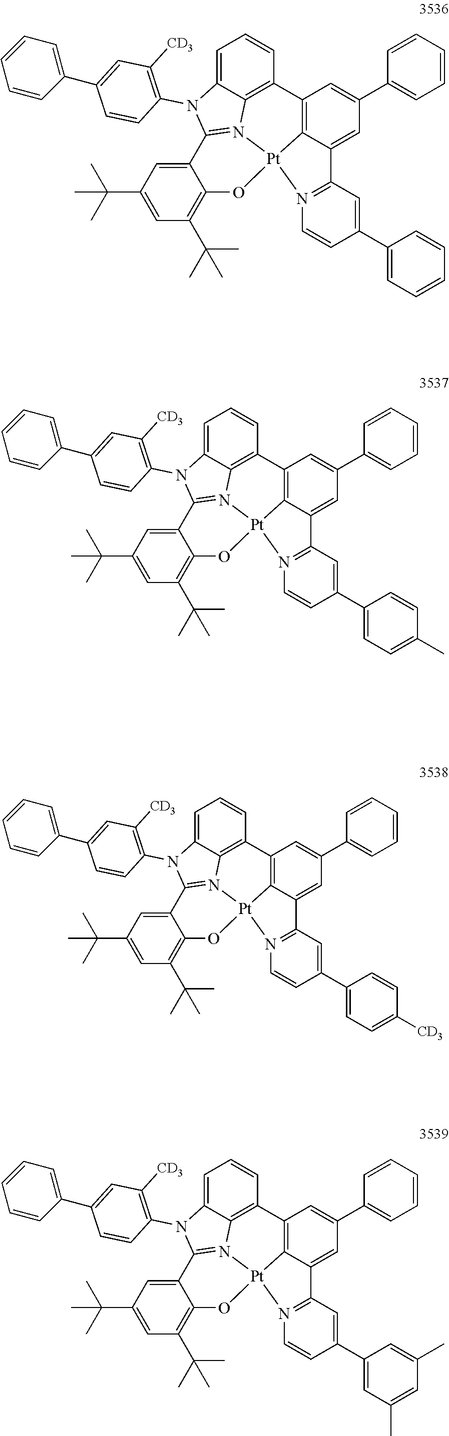

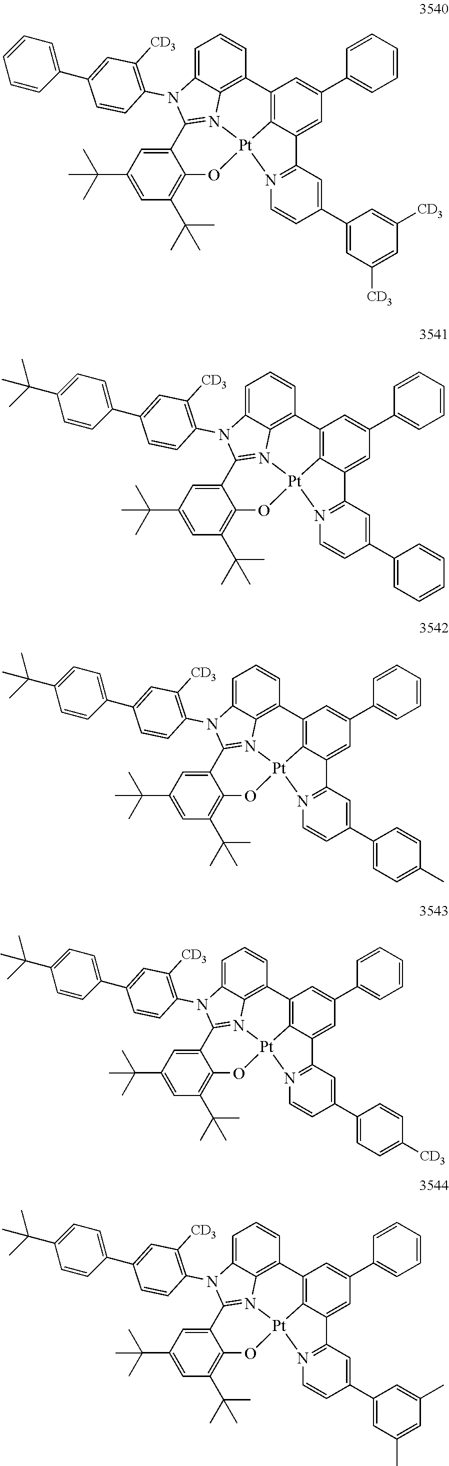

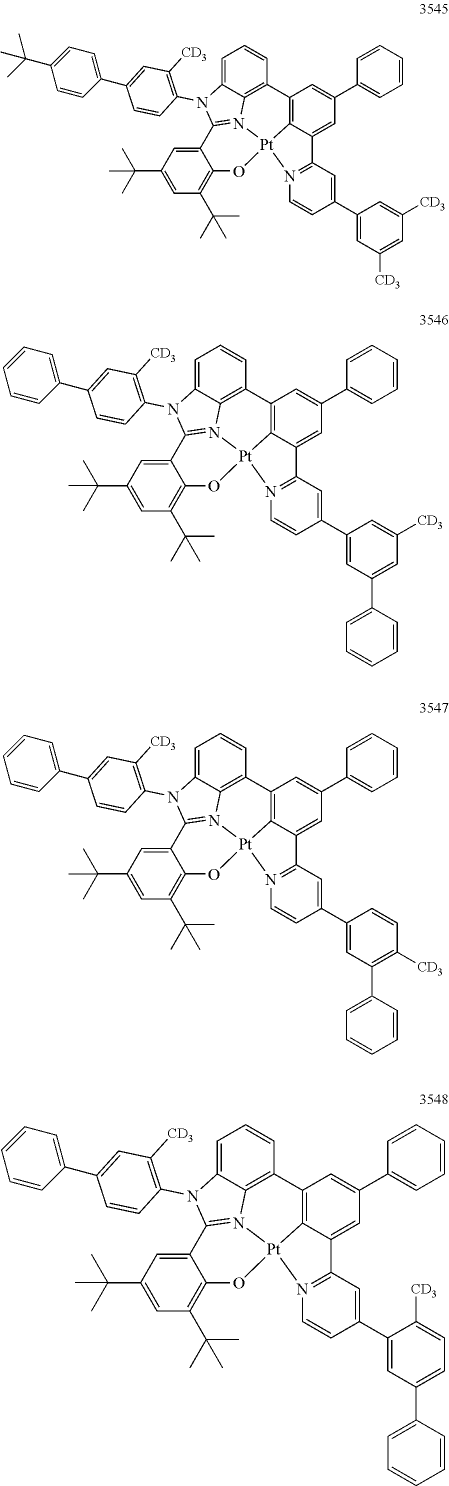

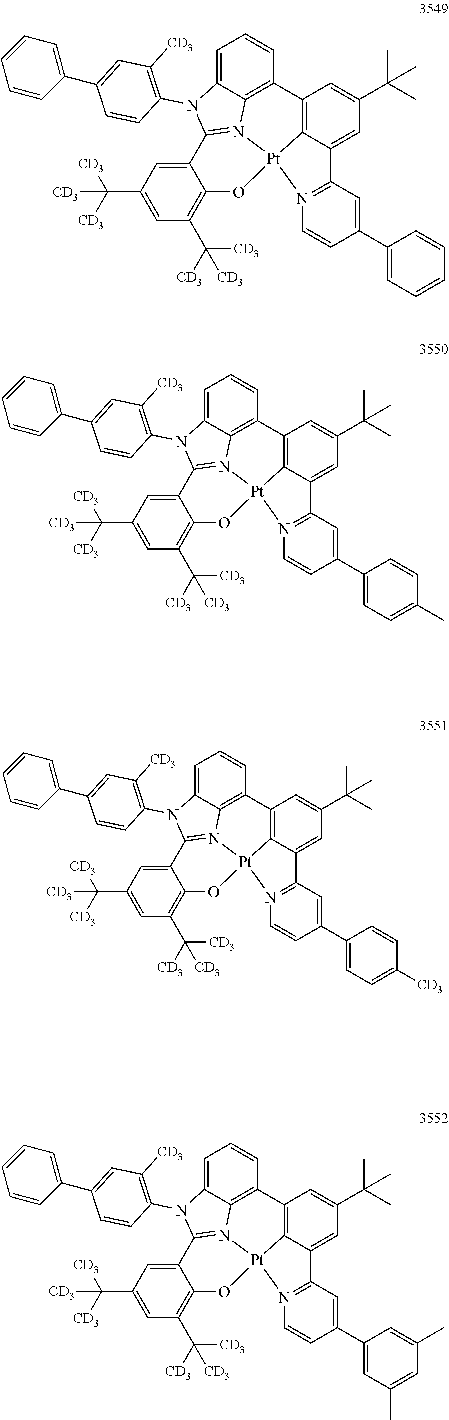

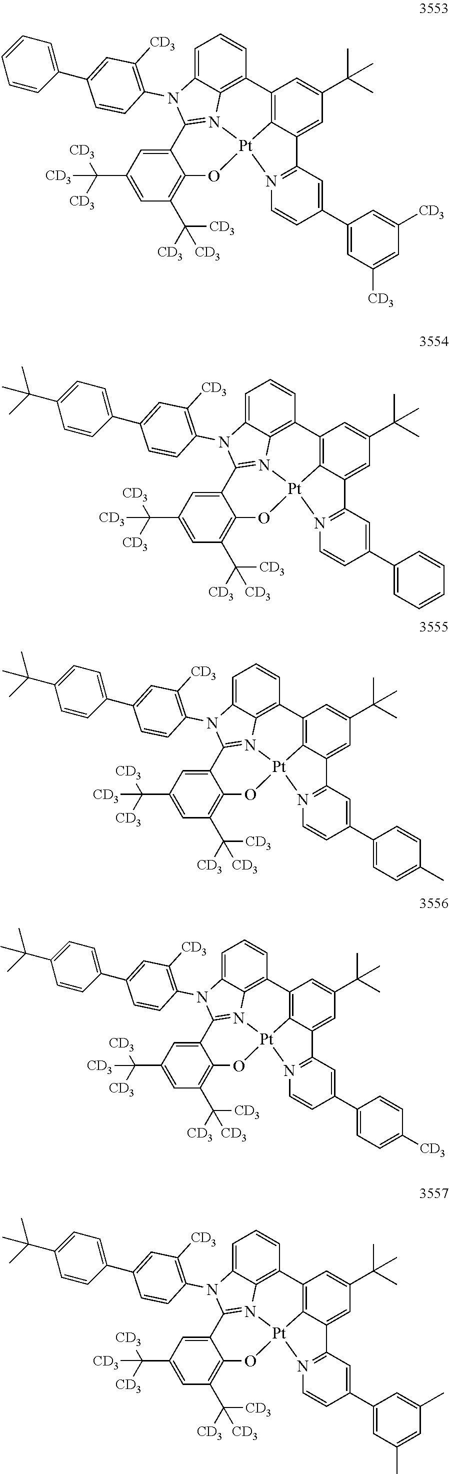

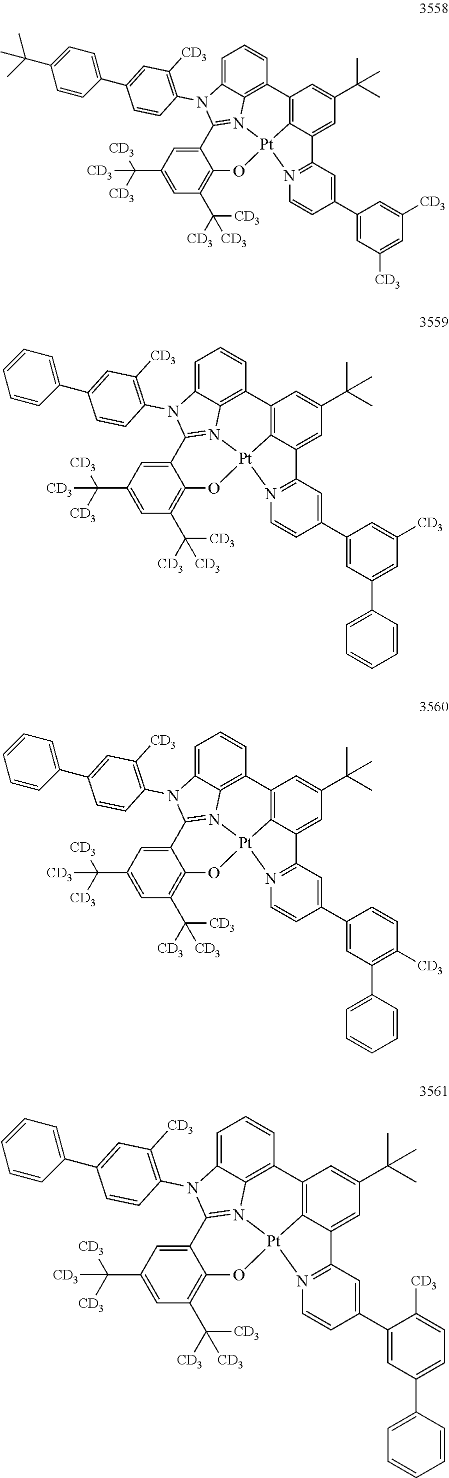

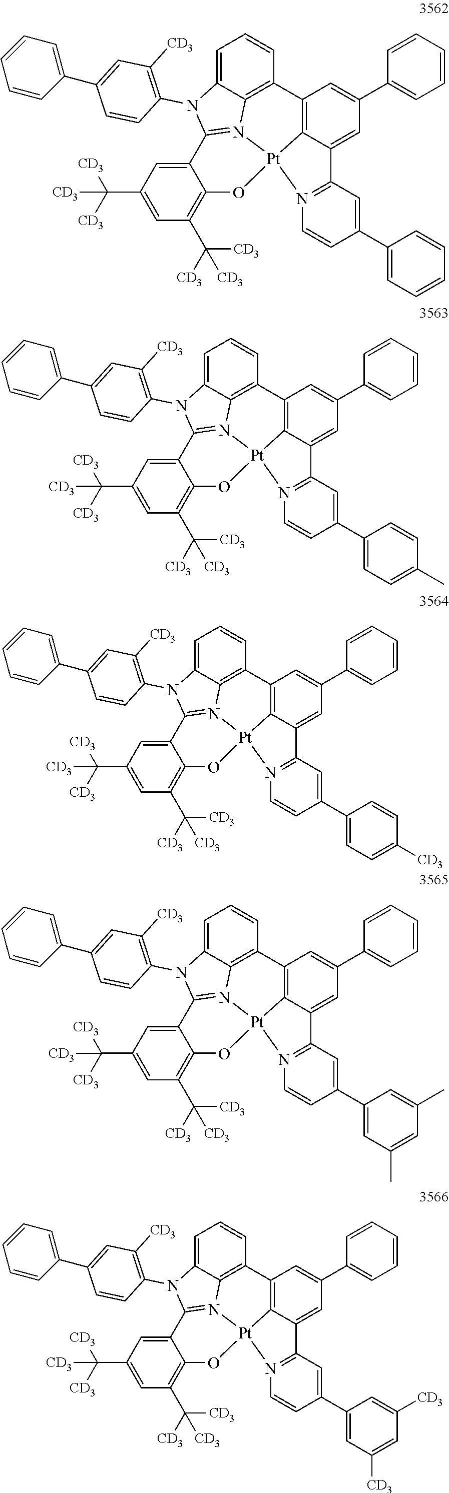

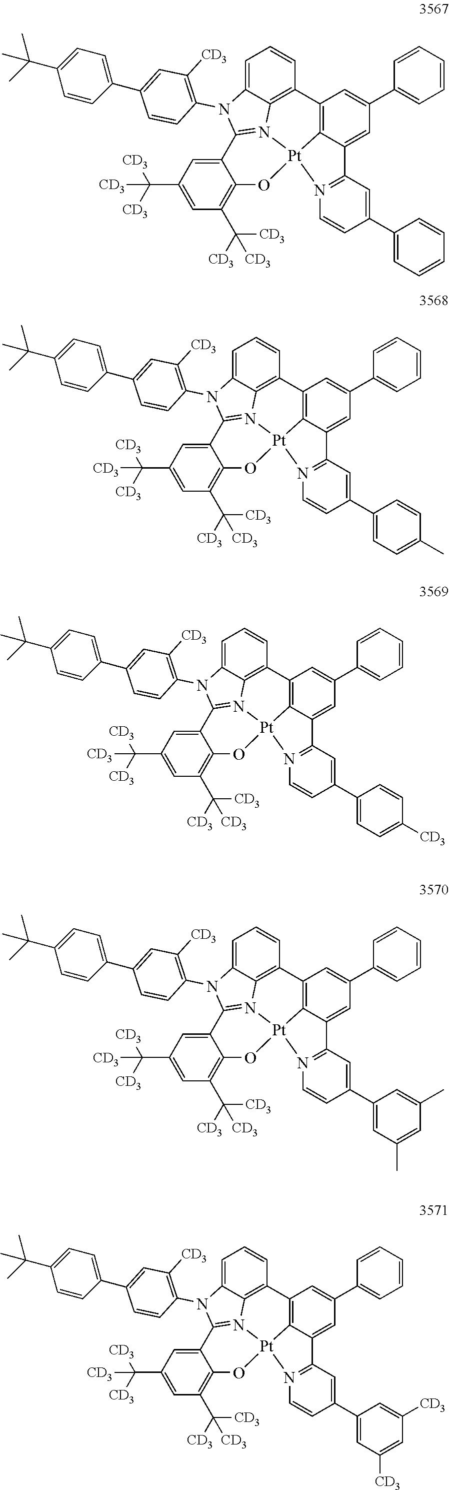

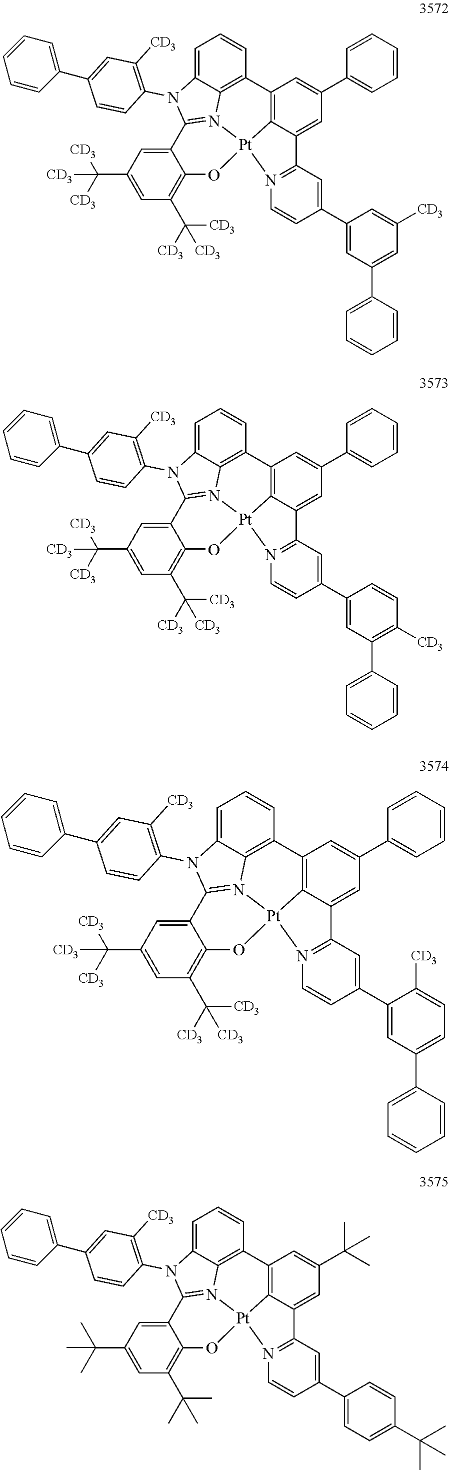

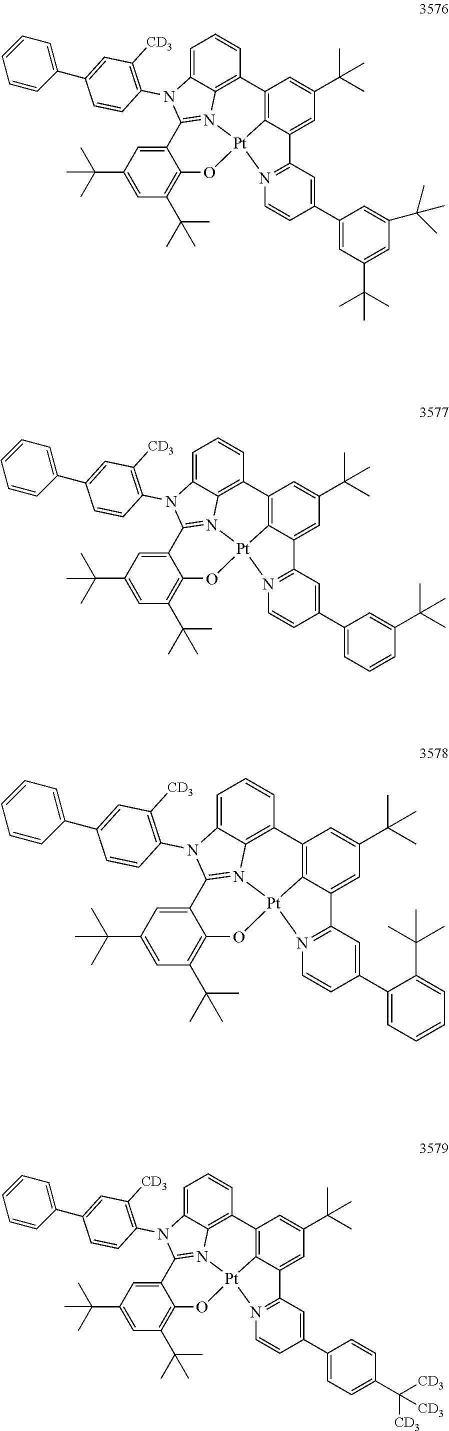

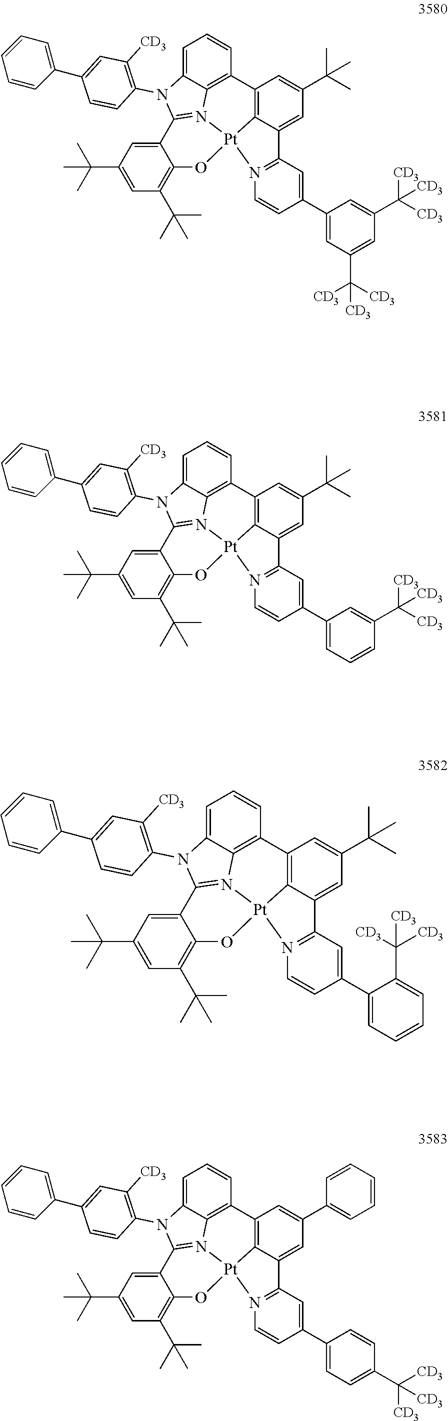

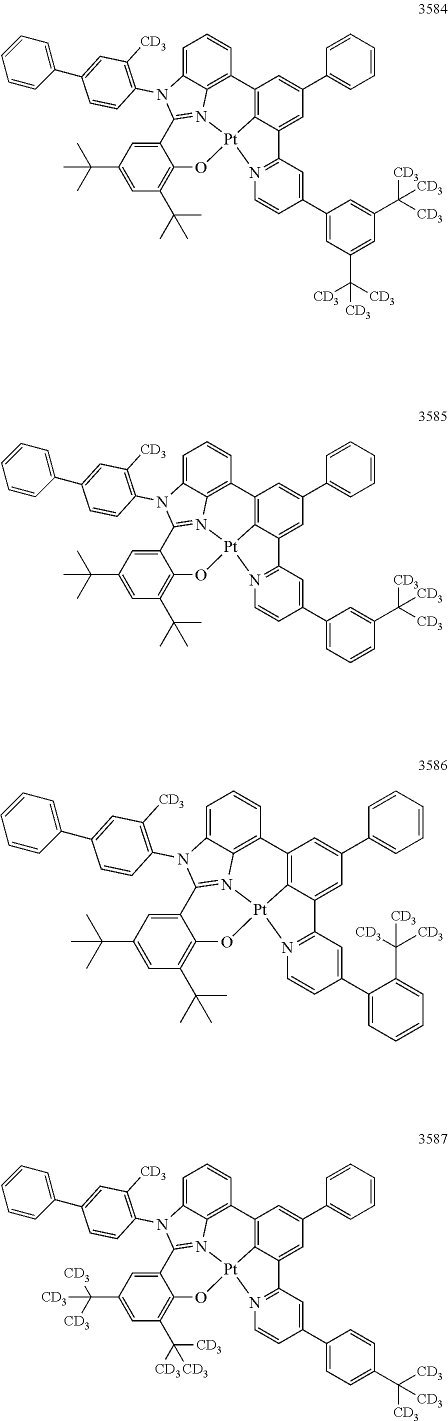

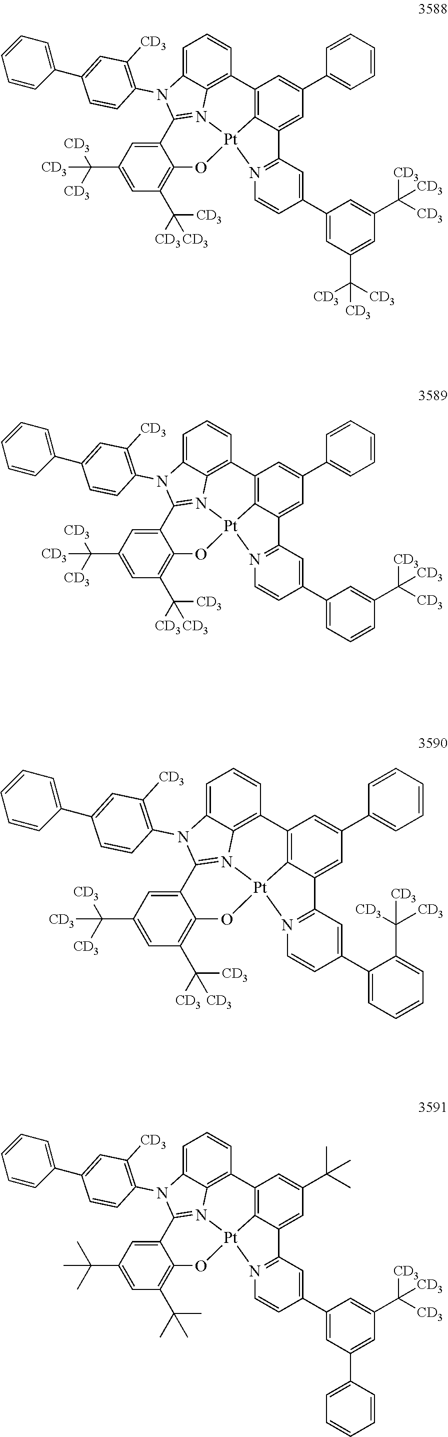

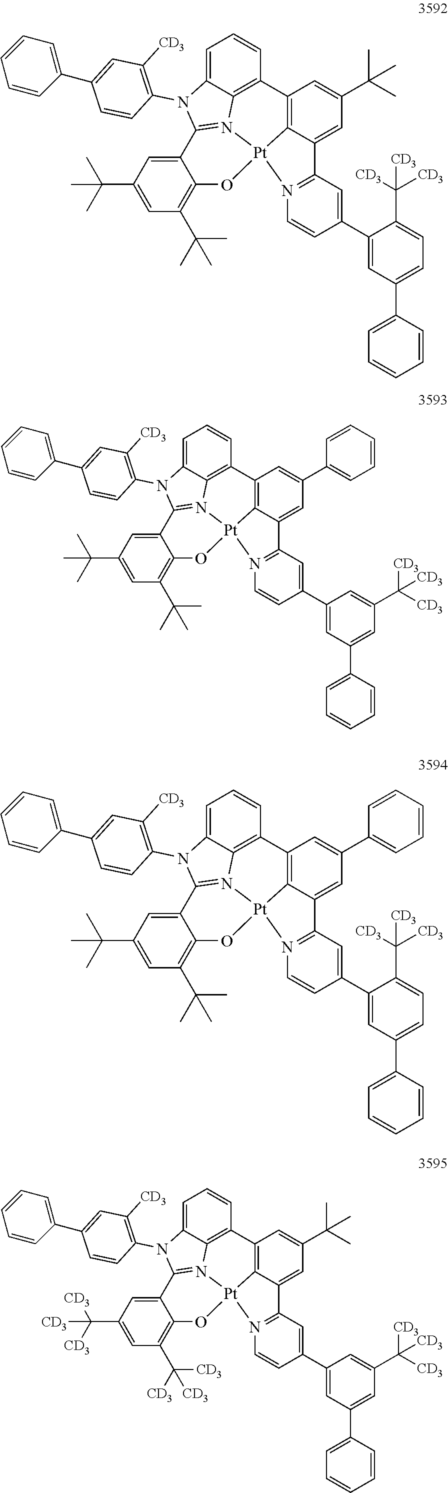

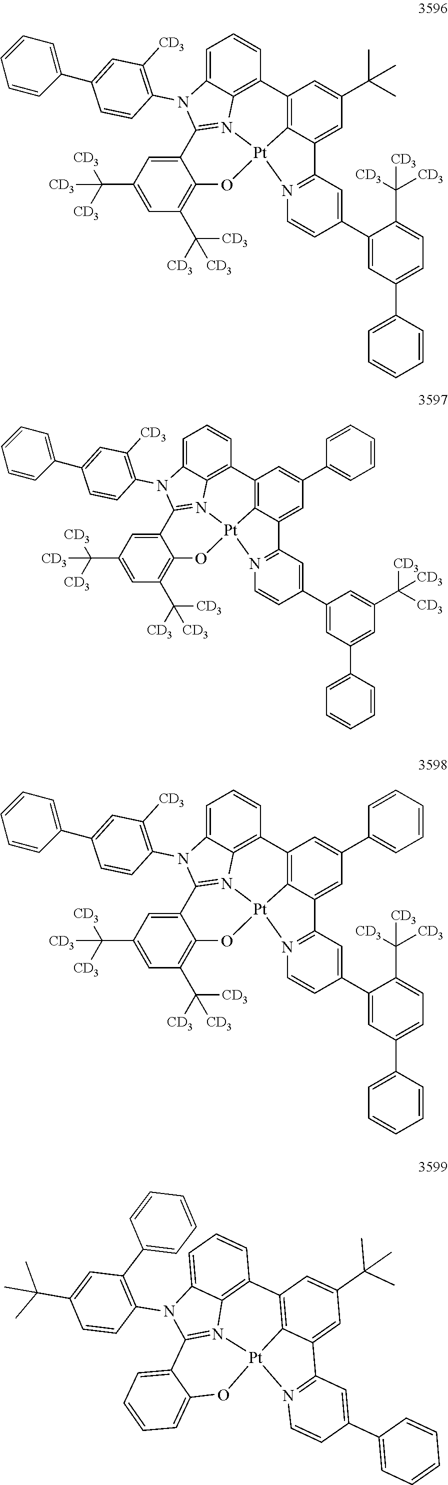

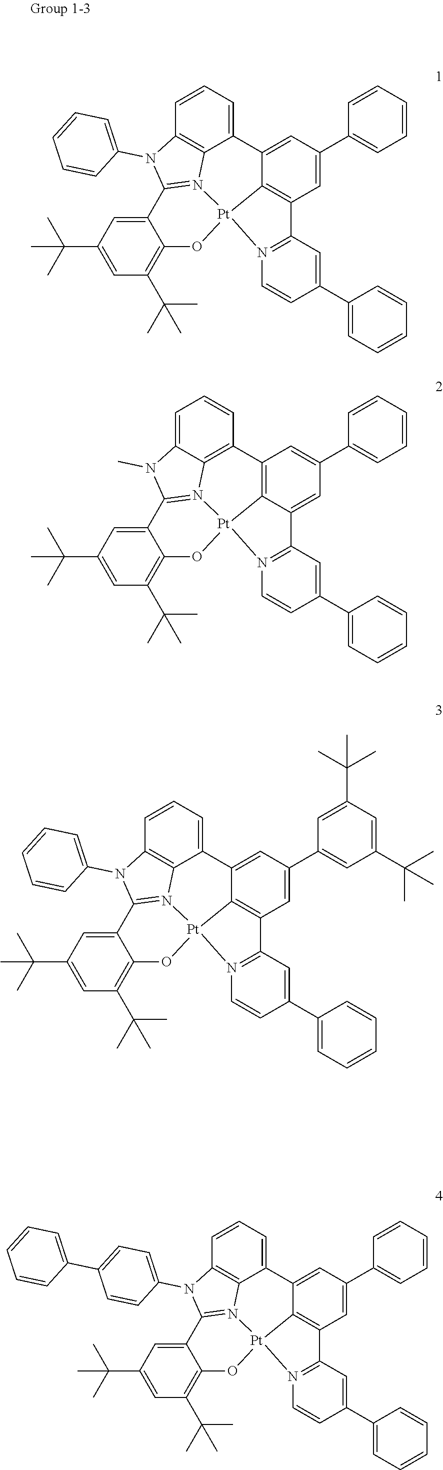

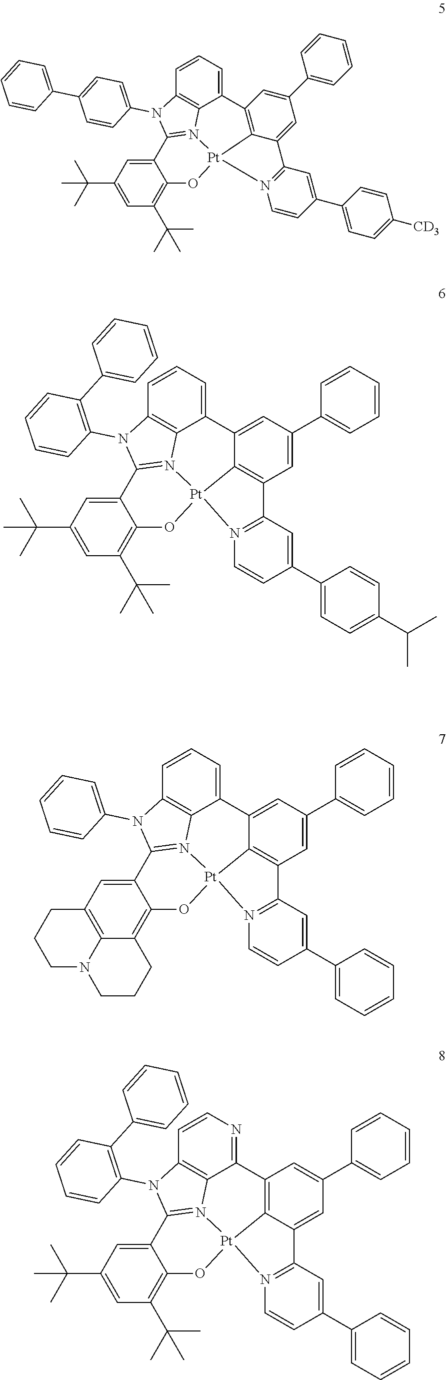

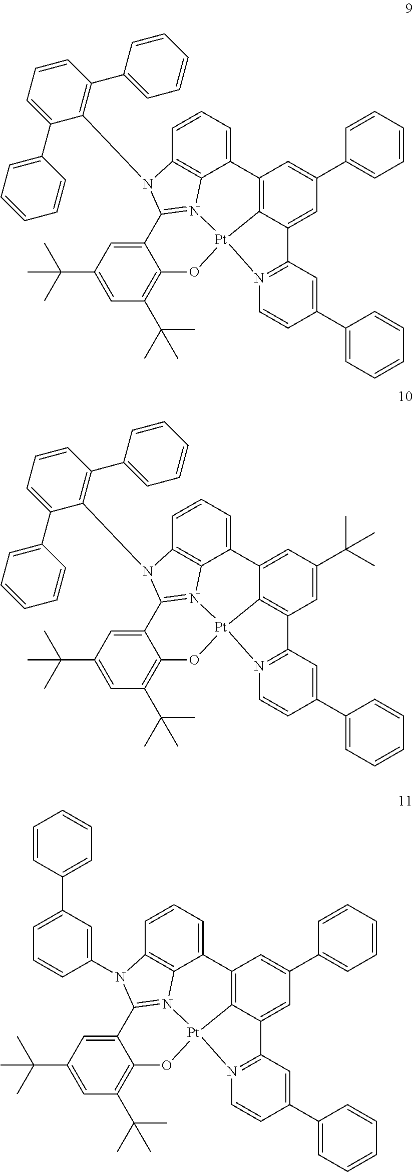

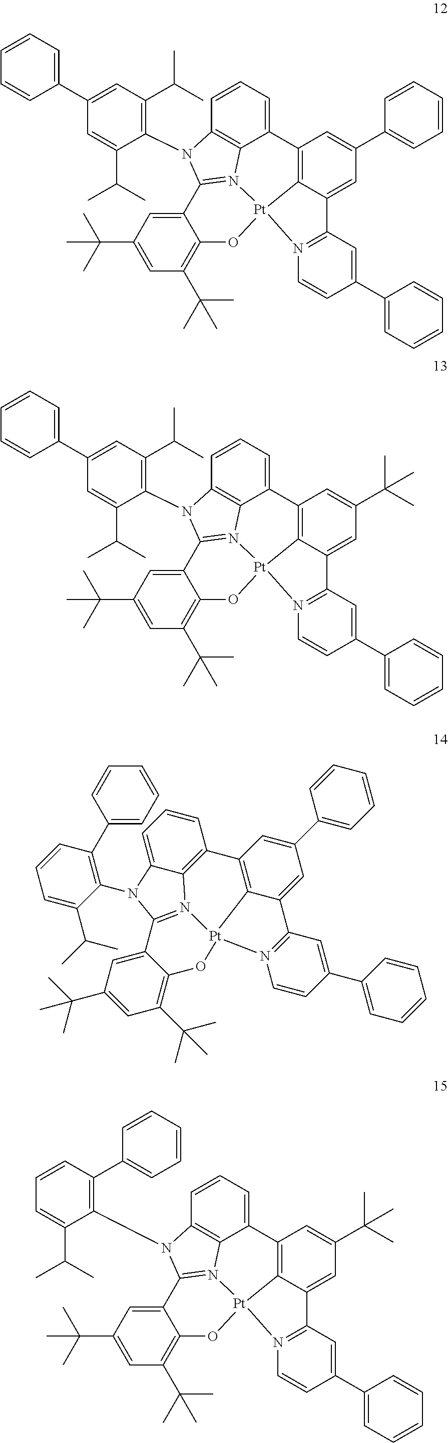

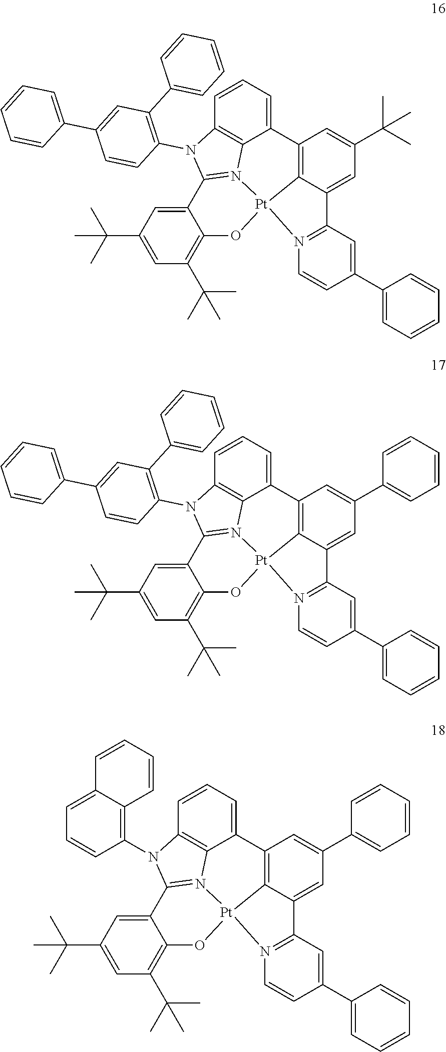

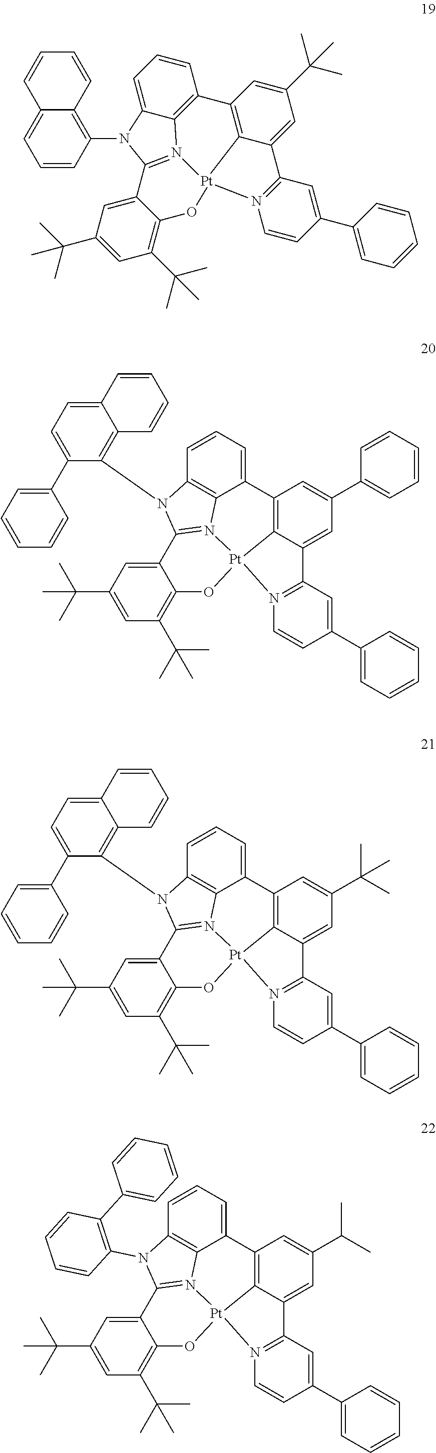

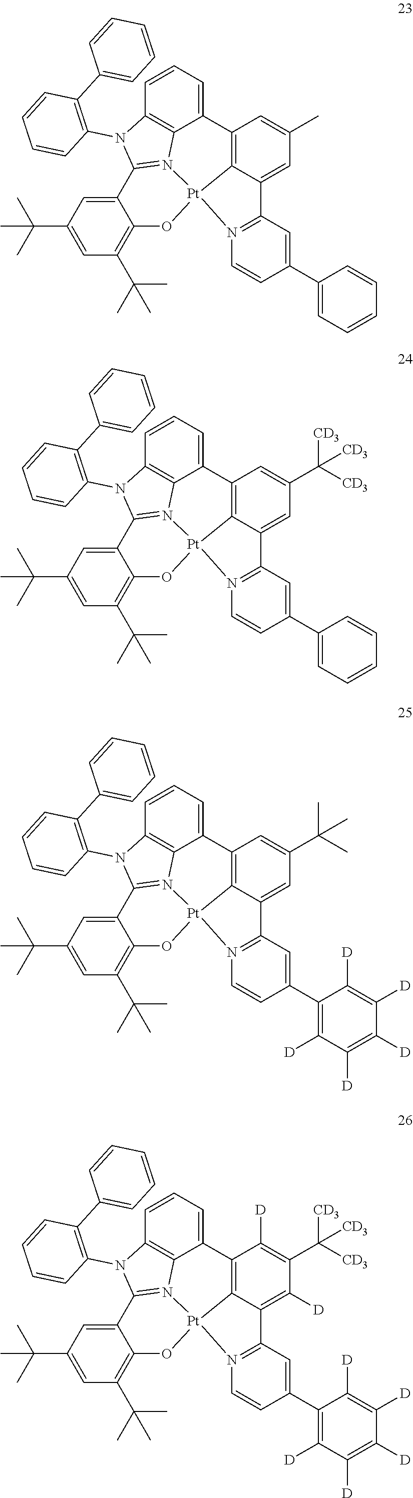

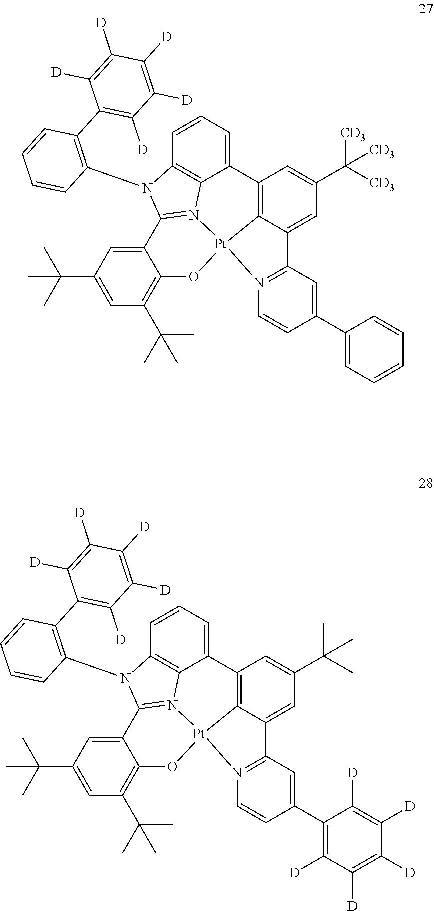

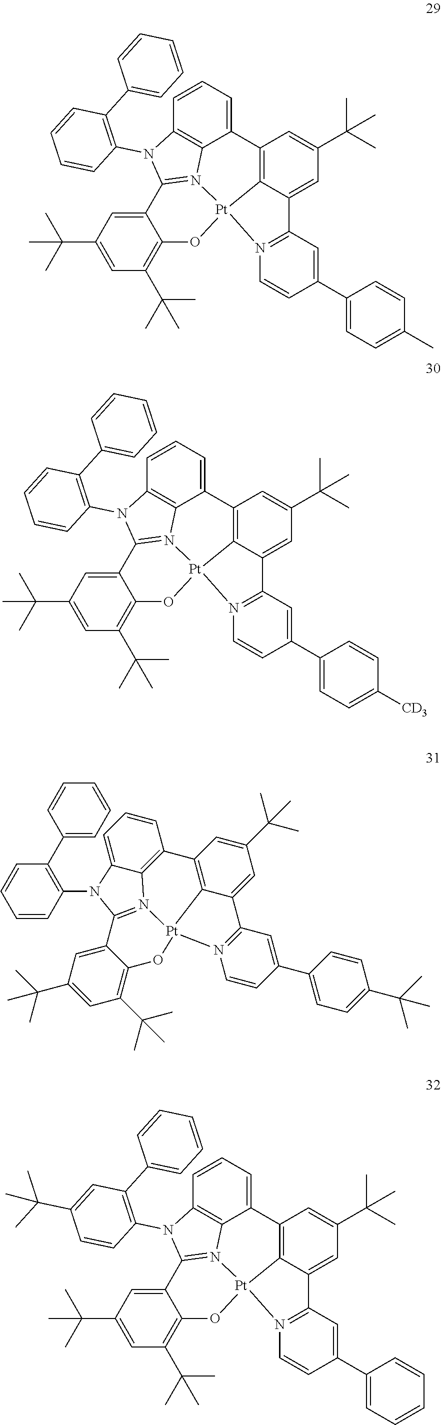

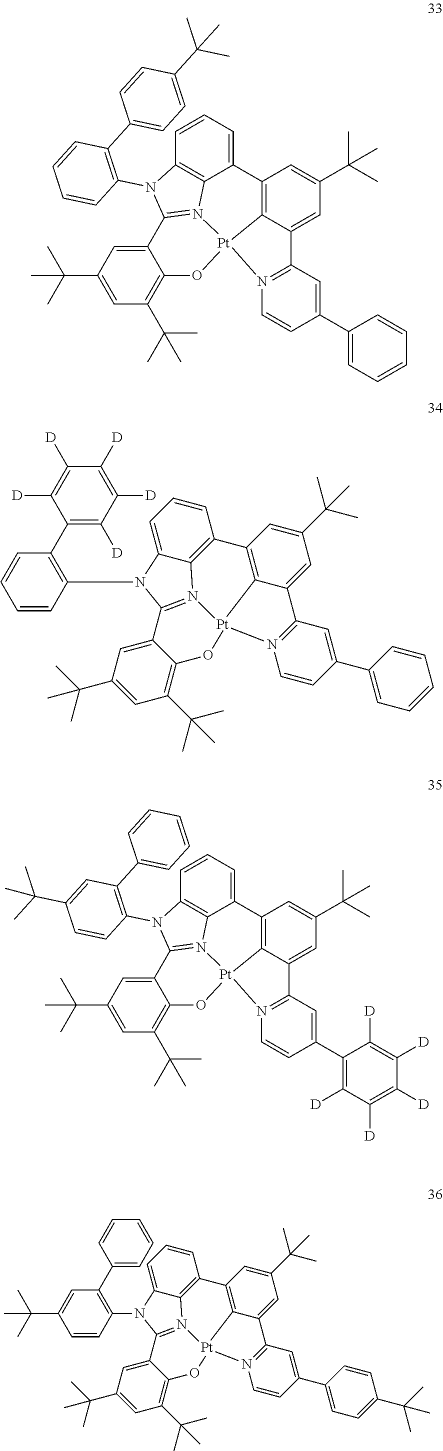

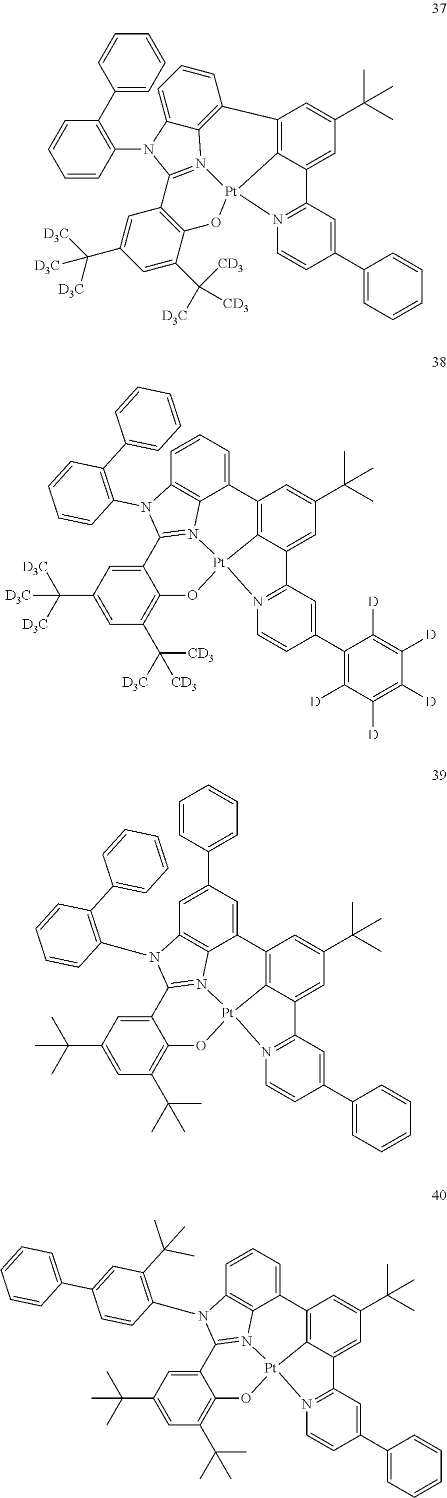

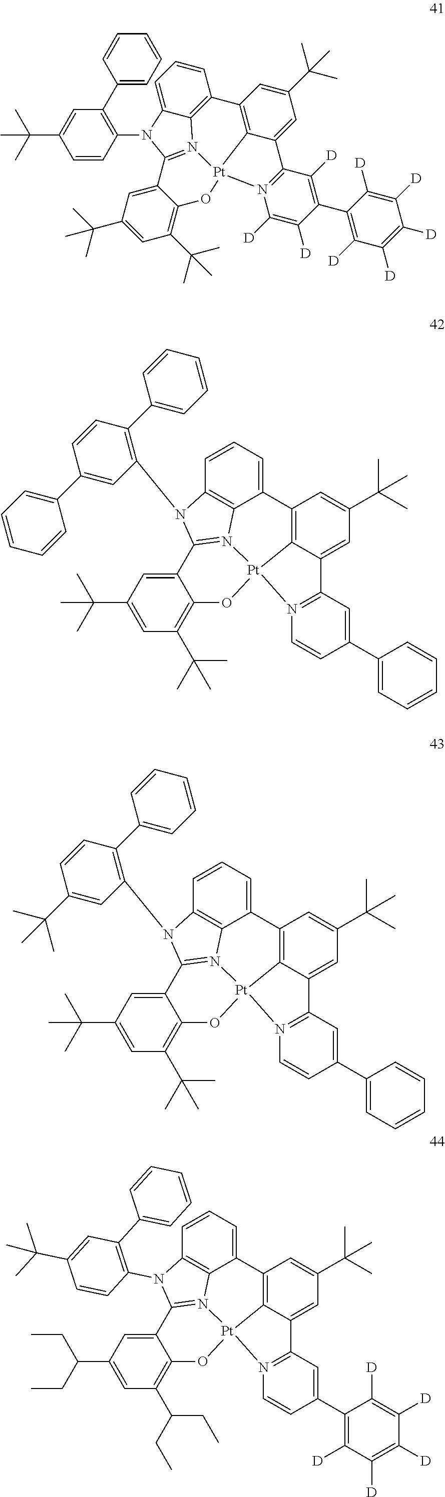

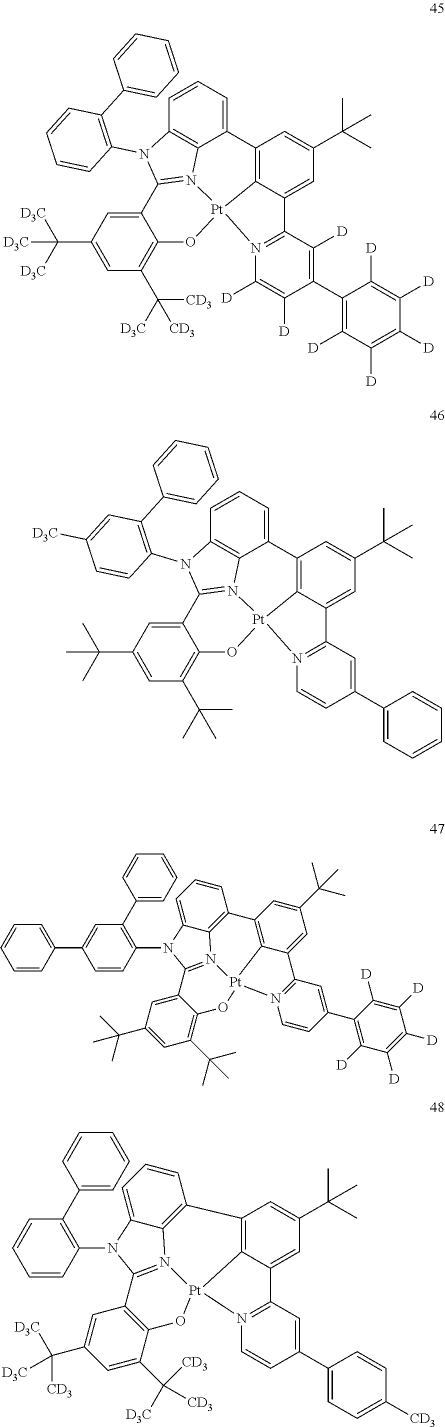

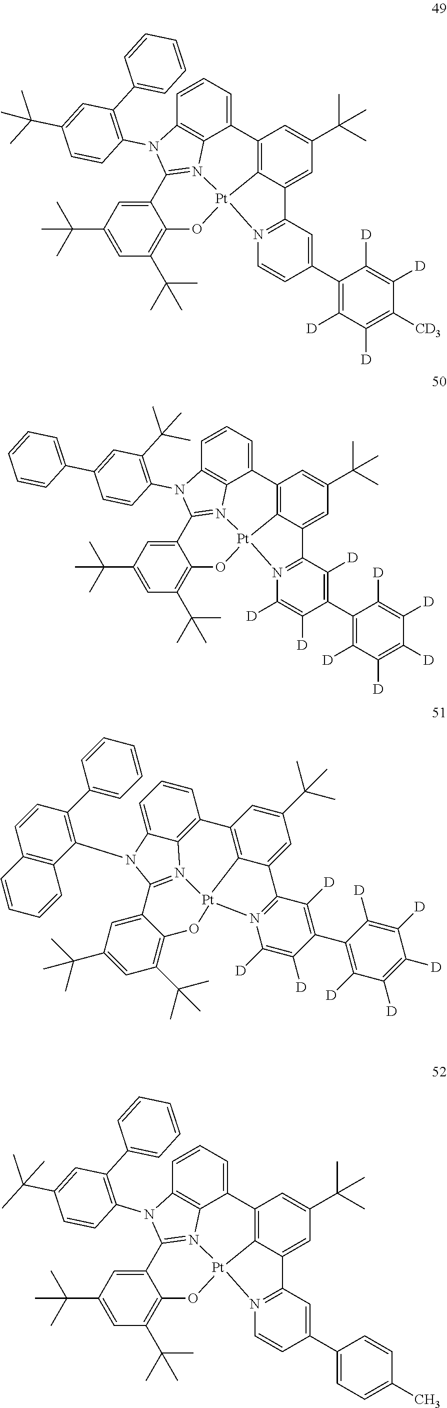

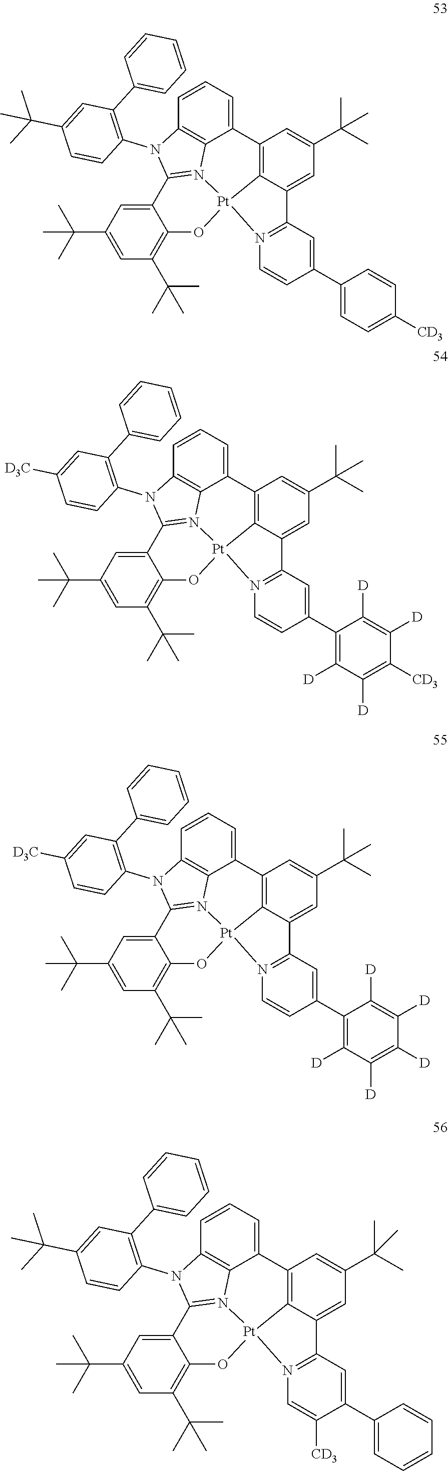

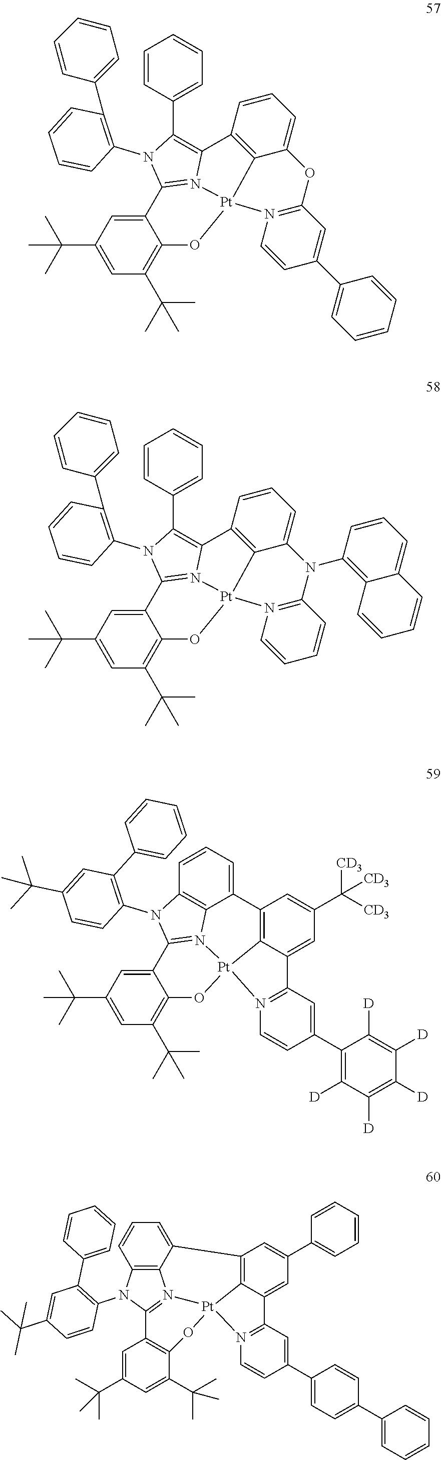

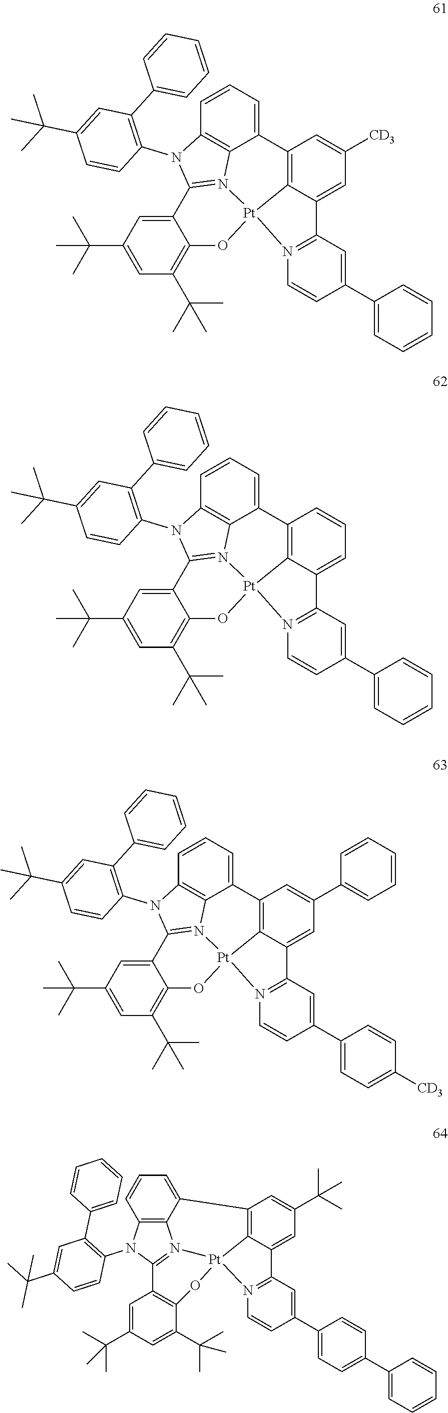

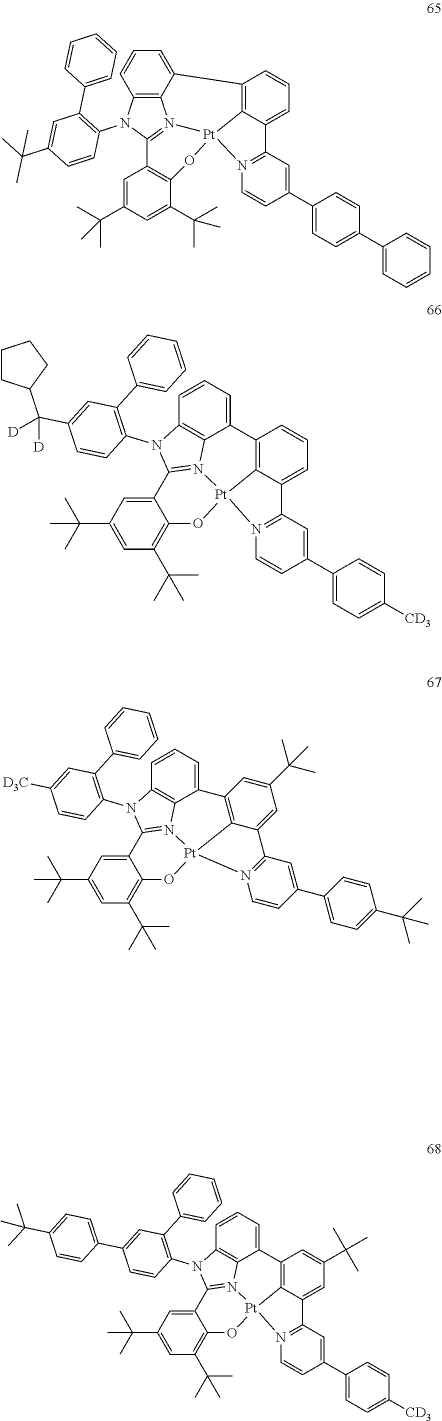

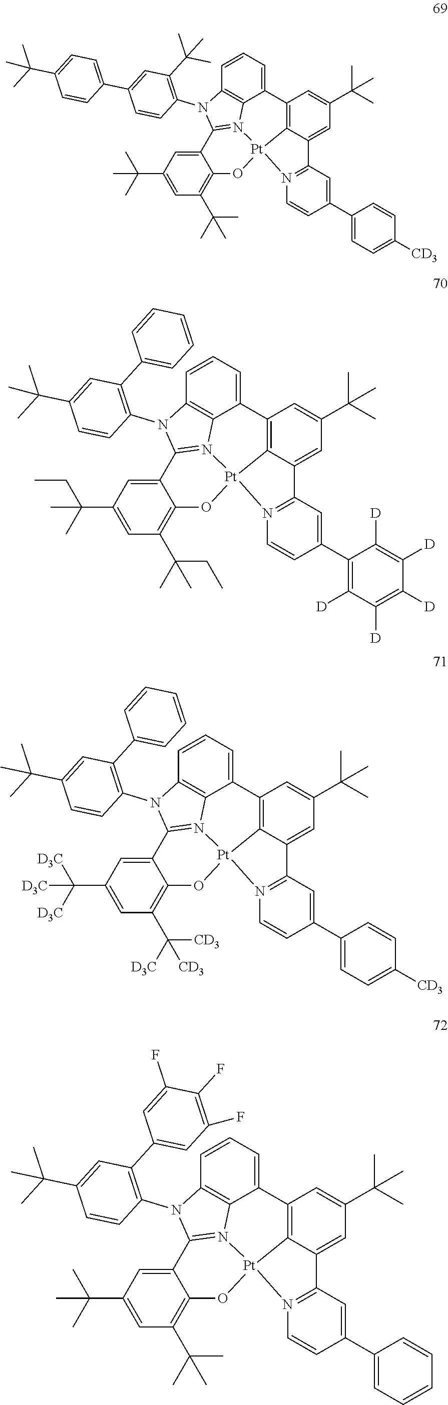

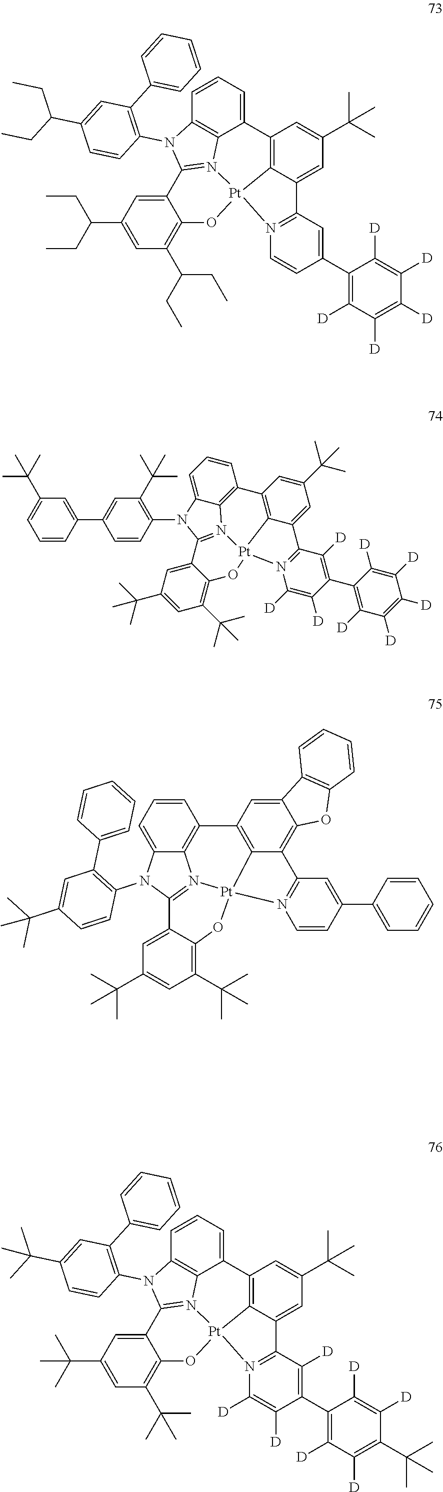

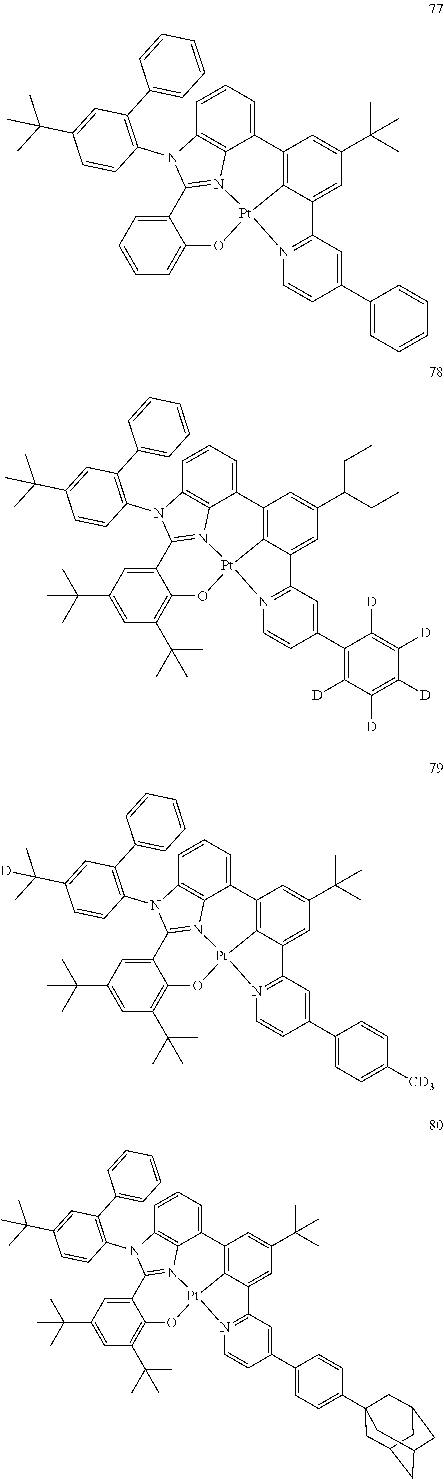

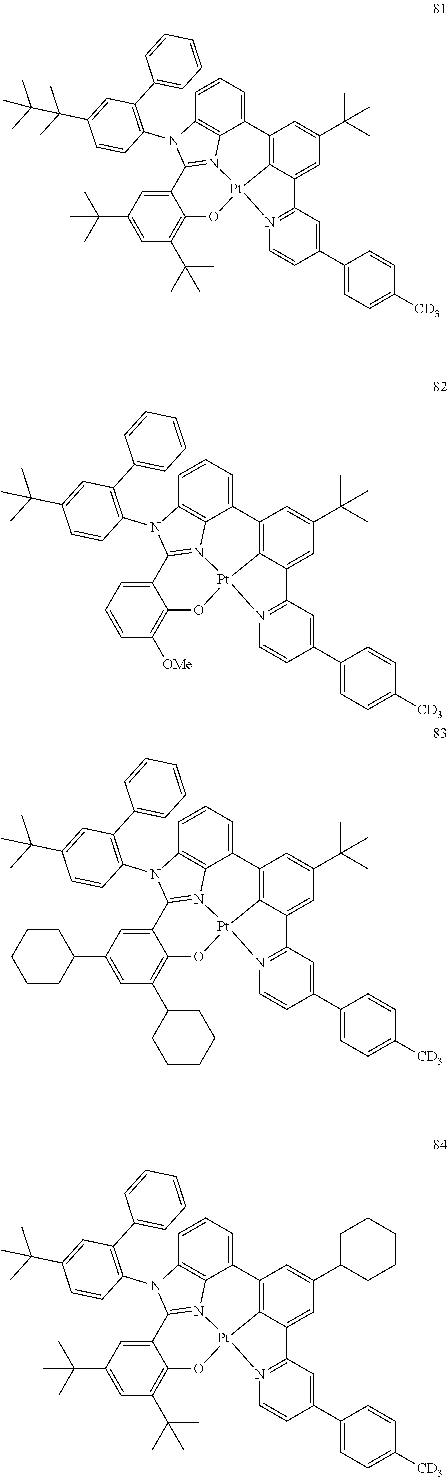

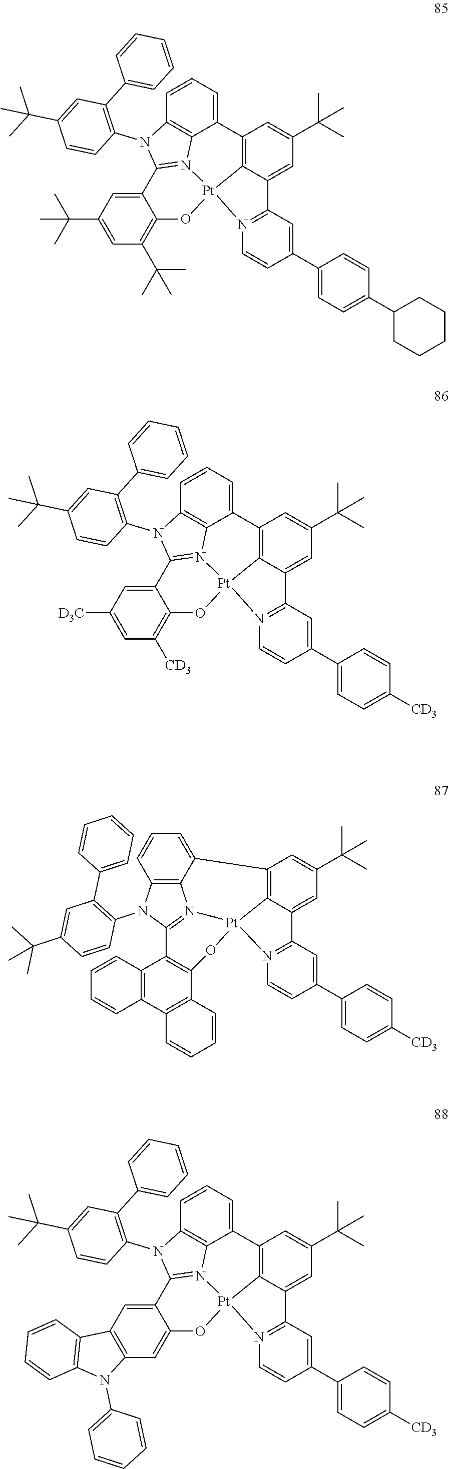

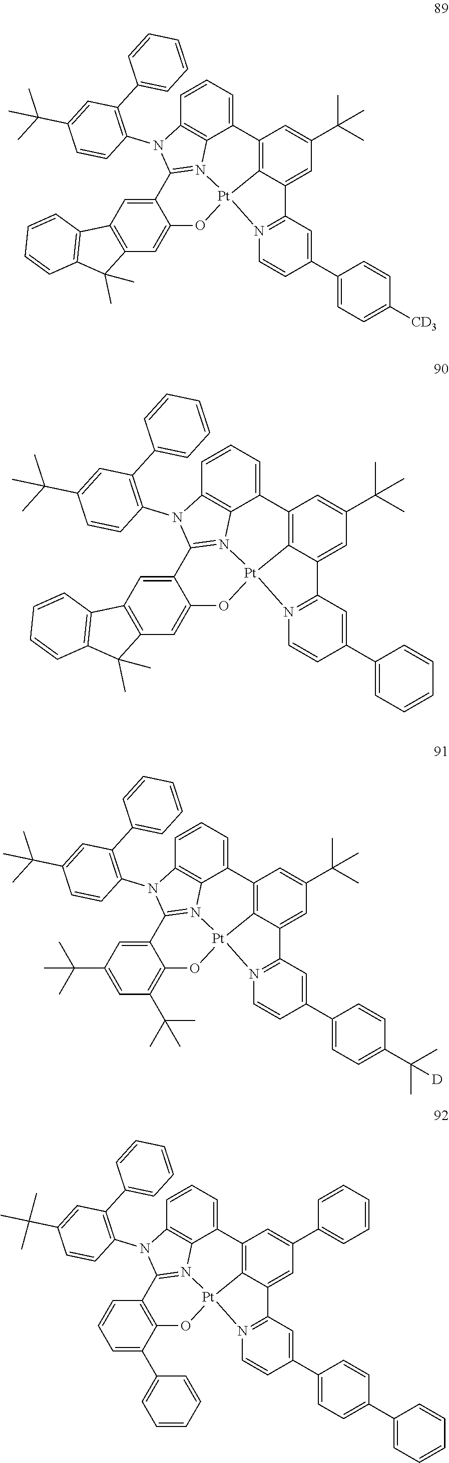

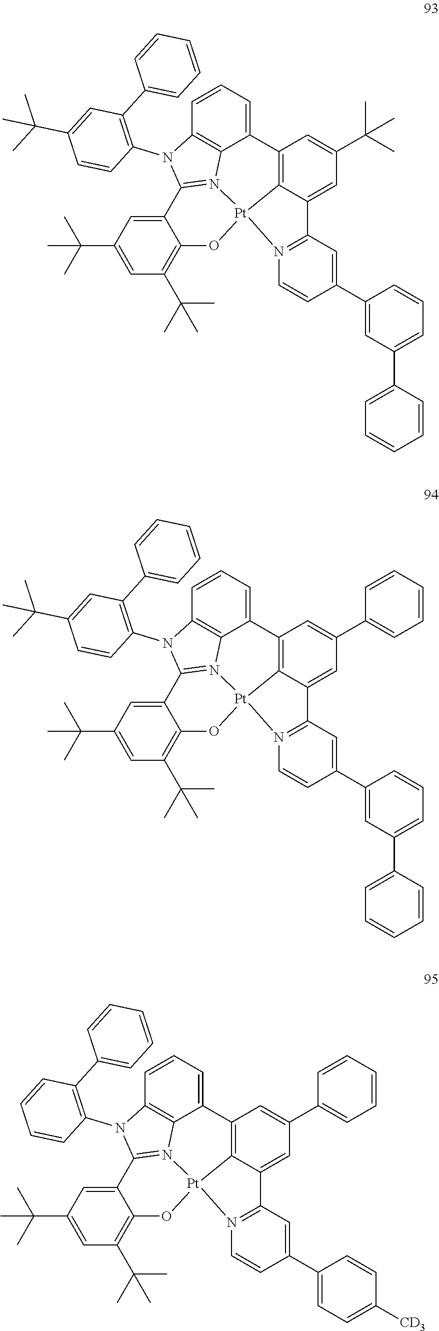

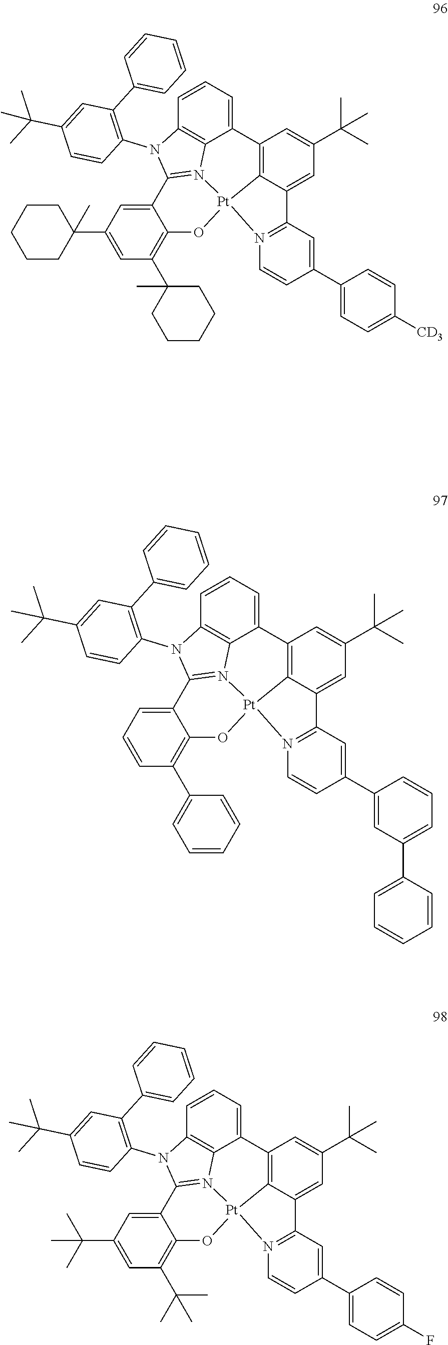

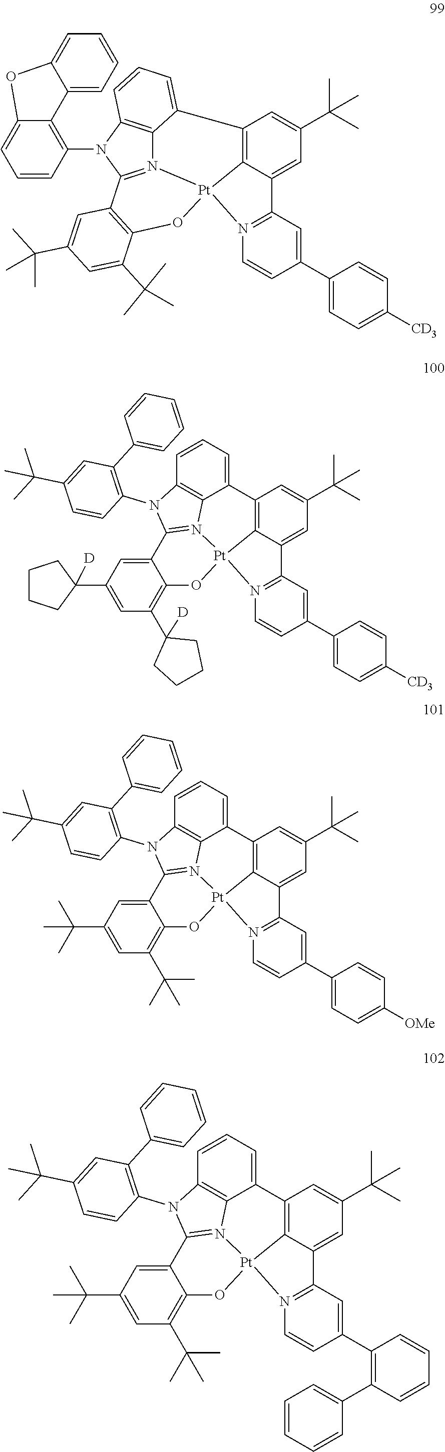

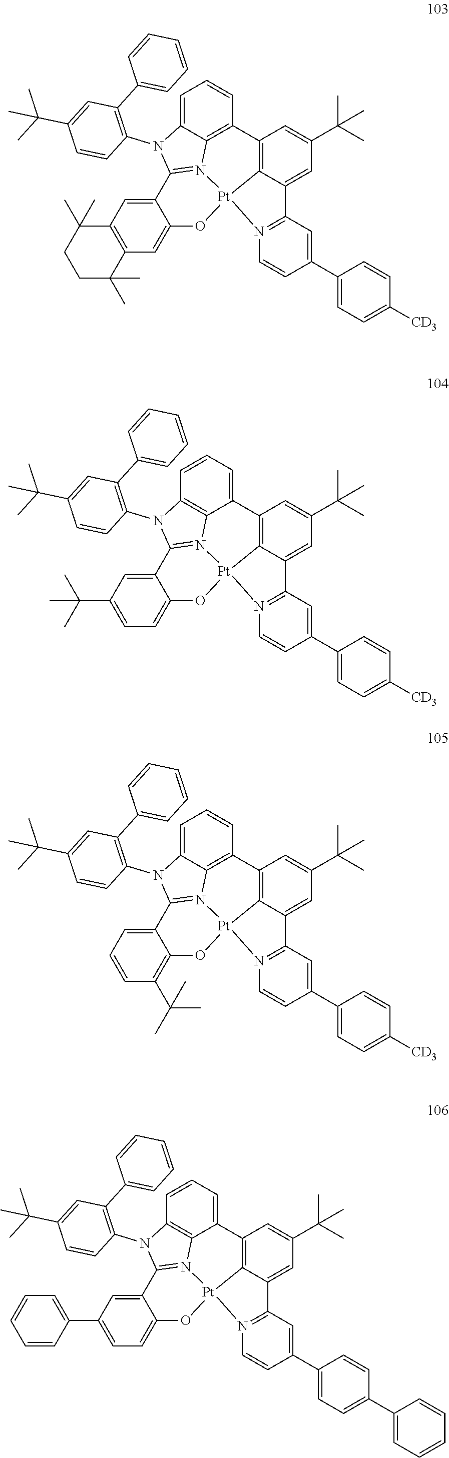

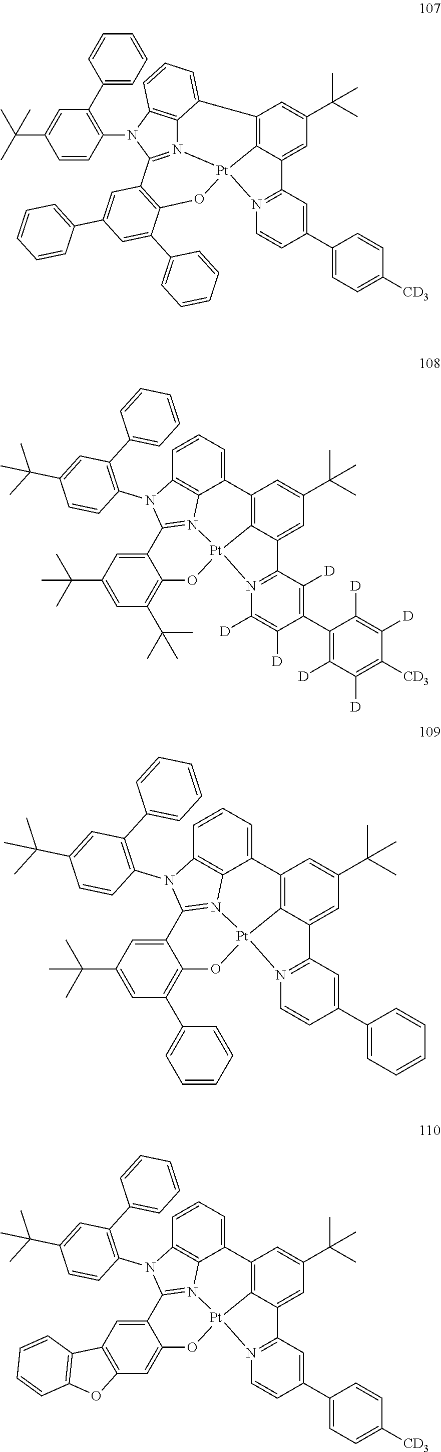

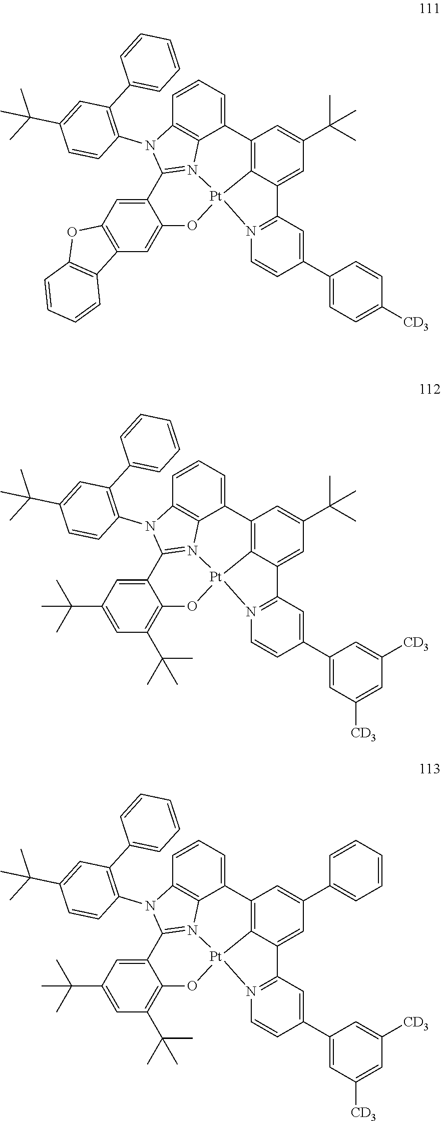

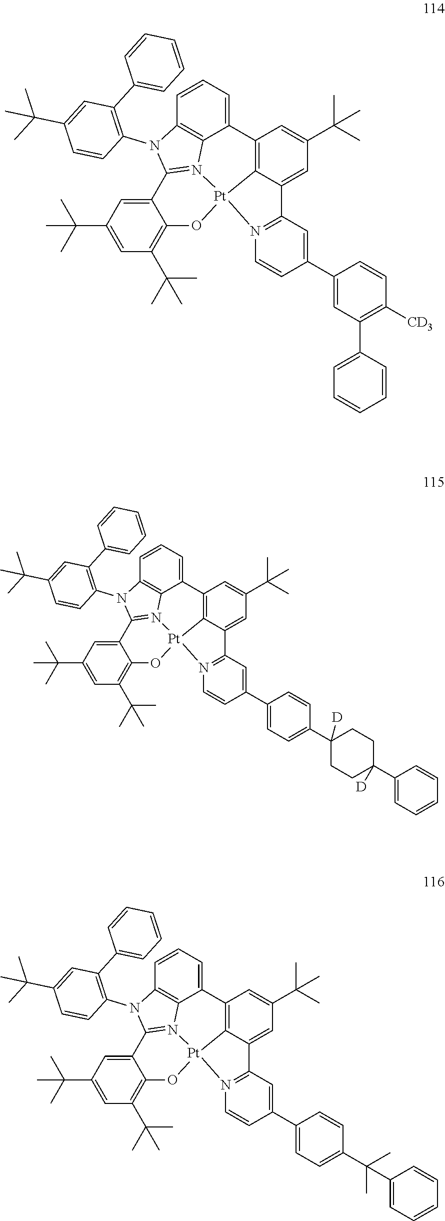

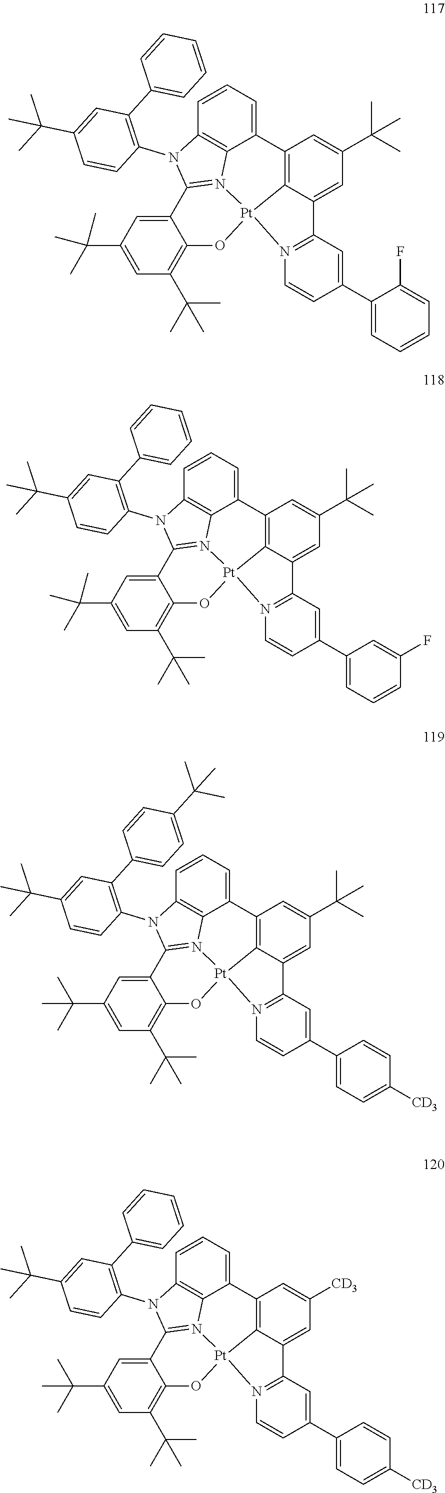

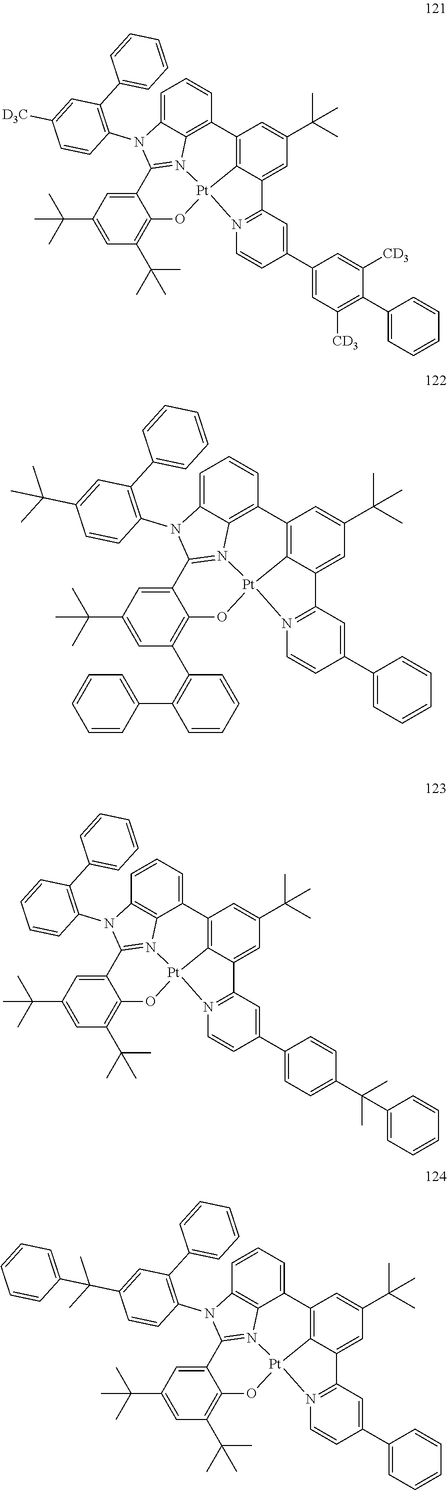

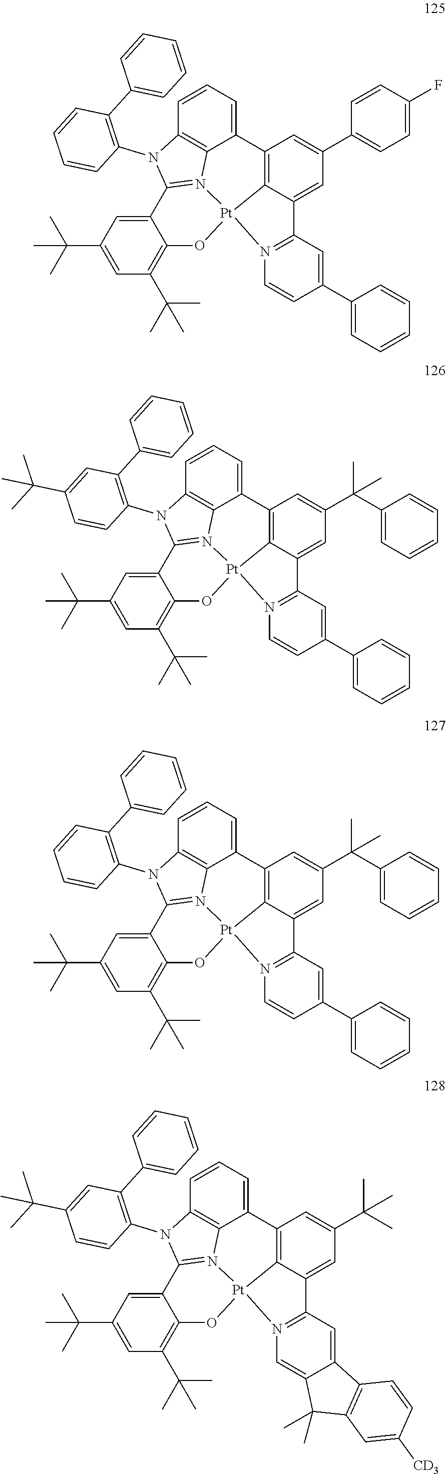

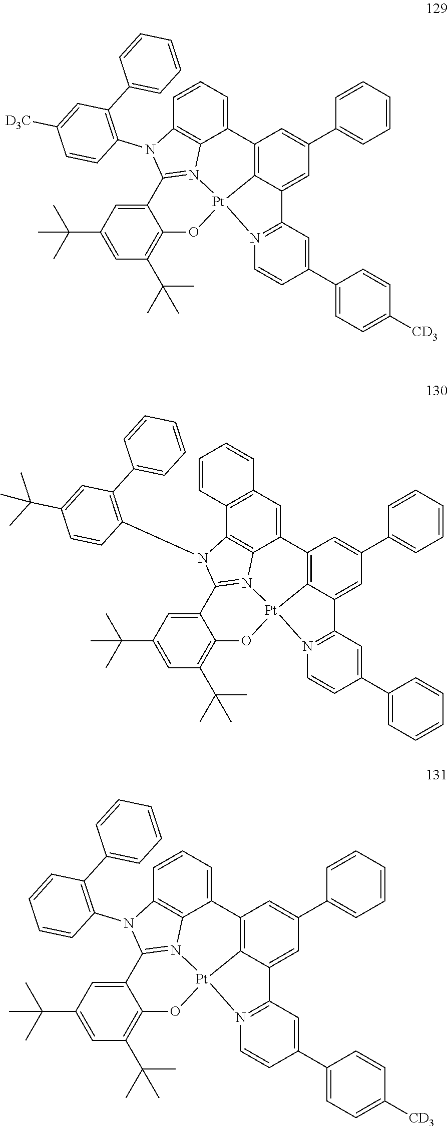

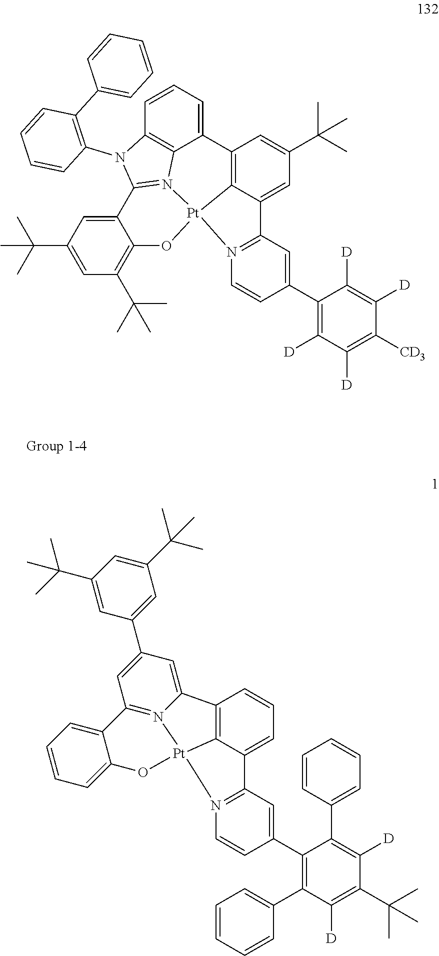

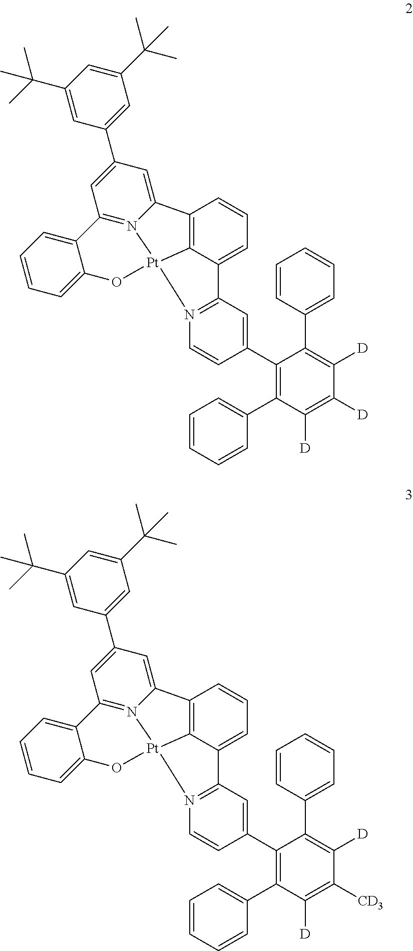

In one or more embodiments, the iridium-containing organometallic compound may be selected from compounds of [Group 2-1] to [Group 2-6]:

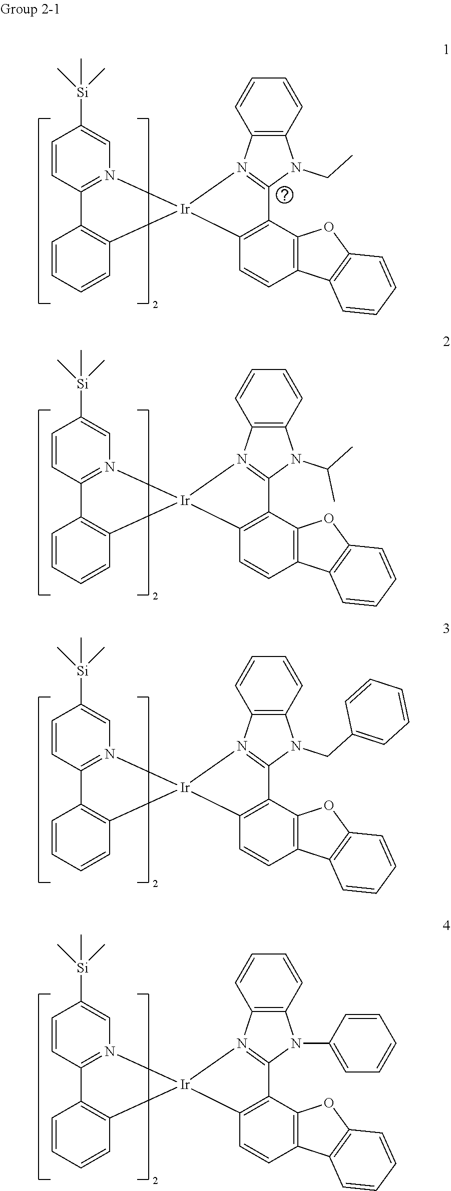

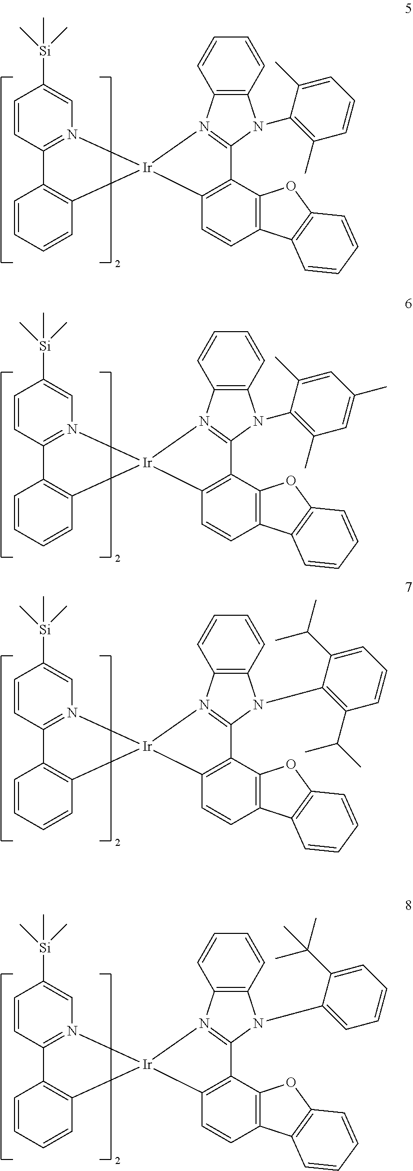

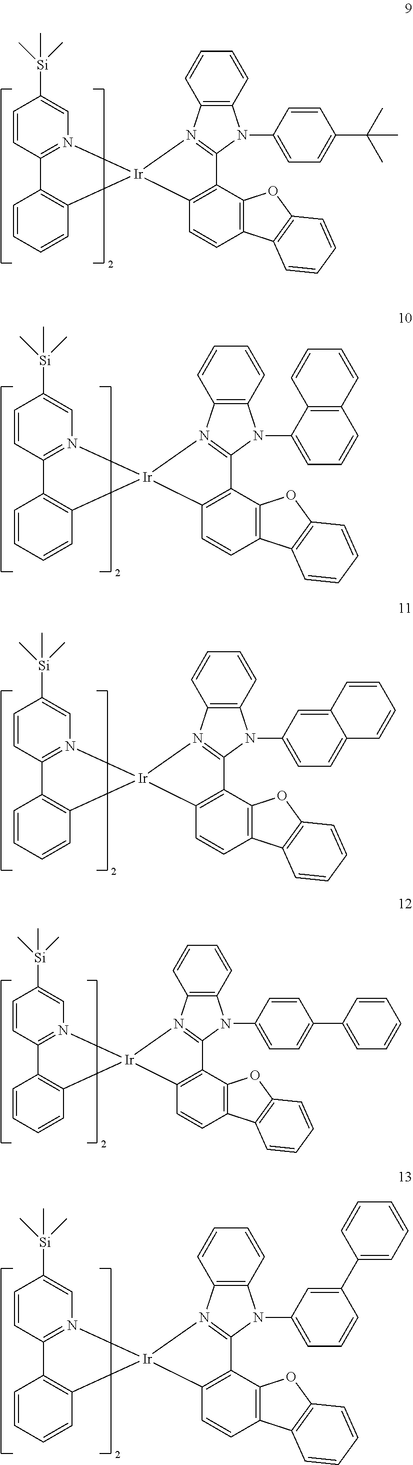

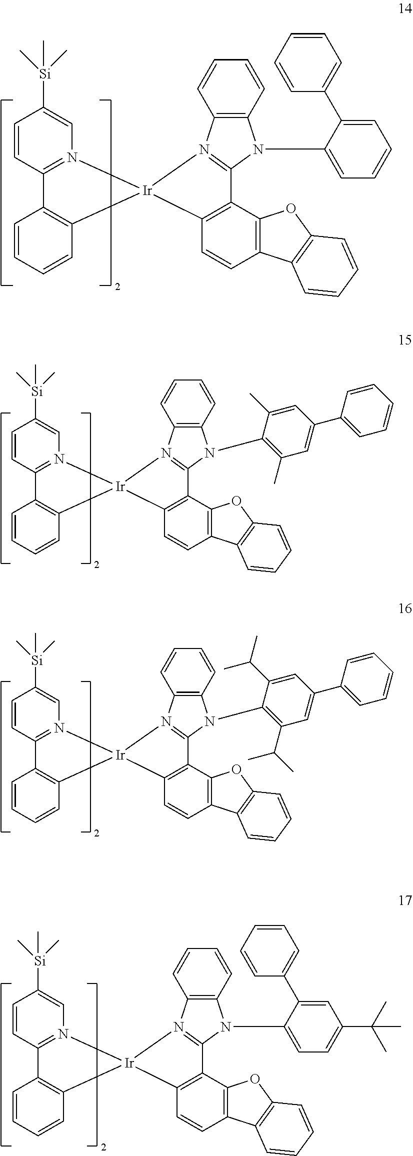

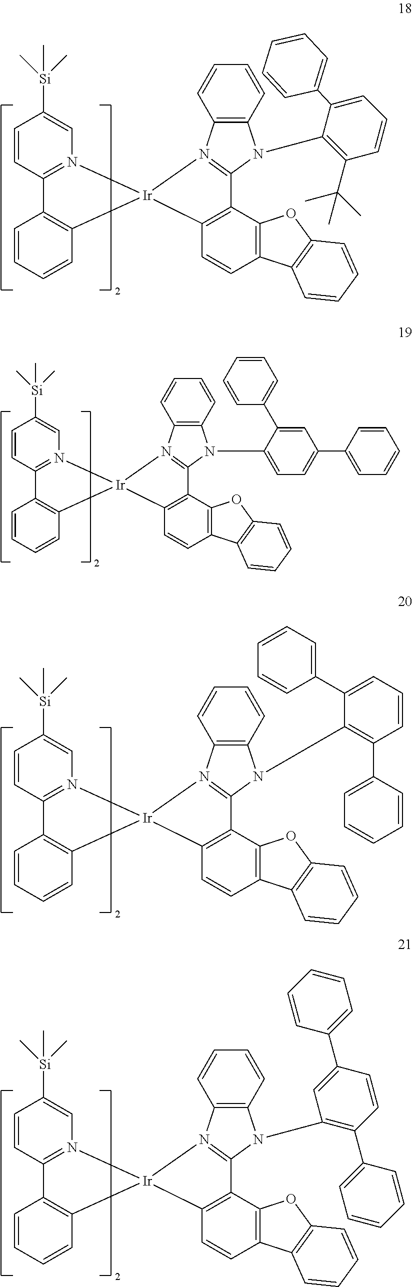

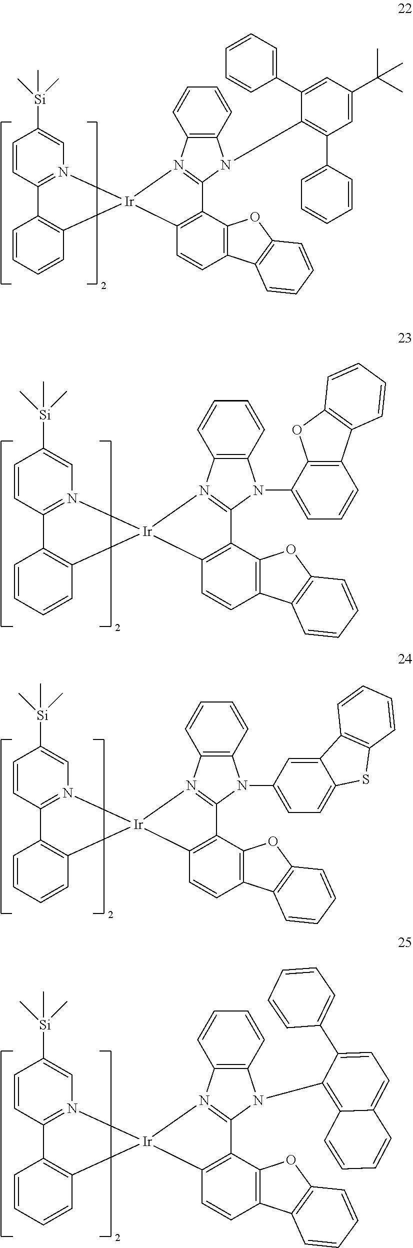

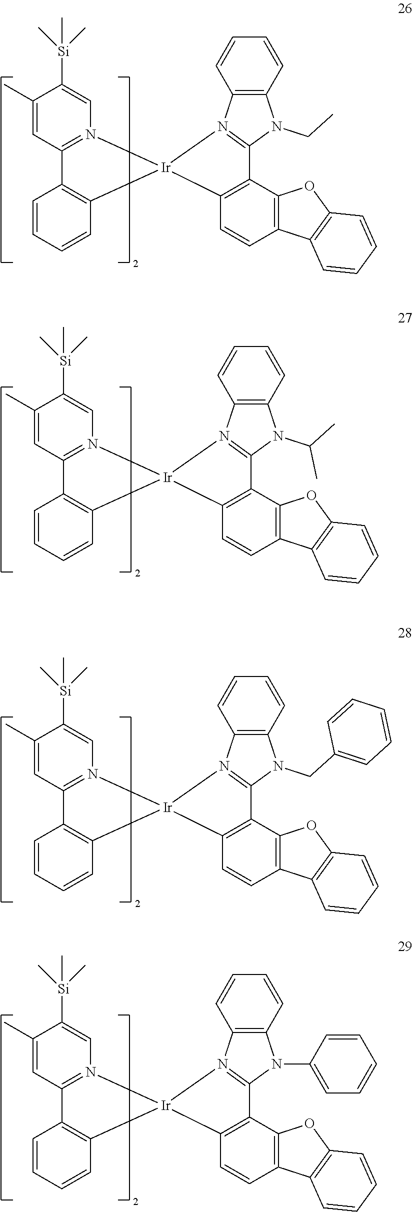

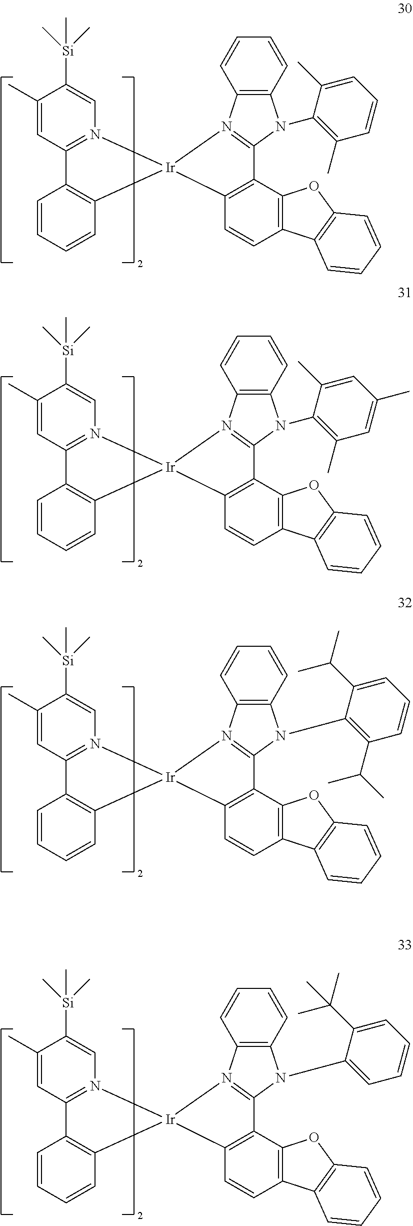

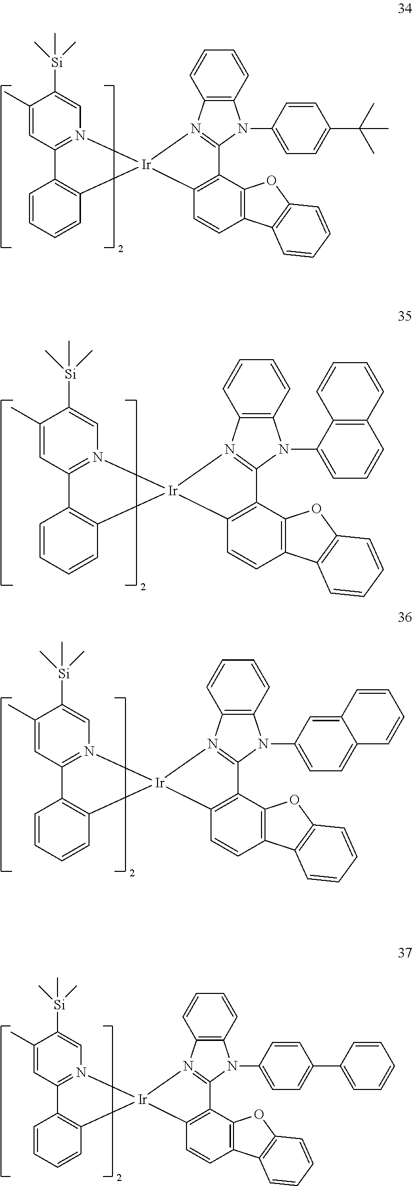

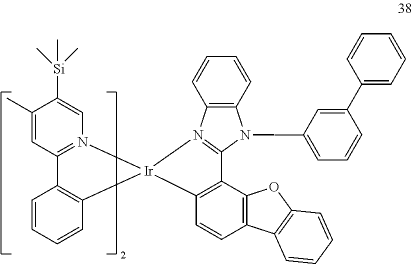

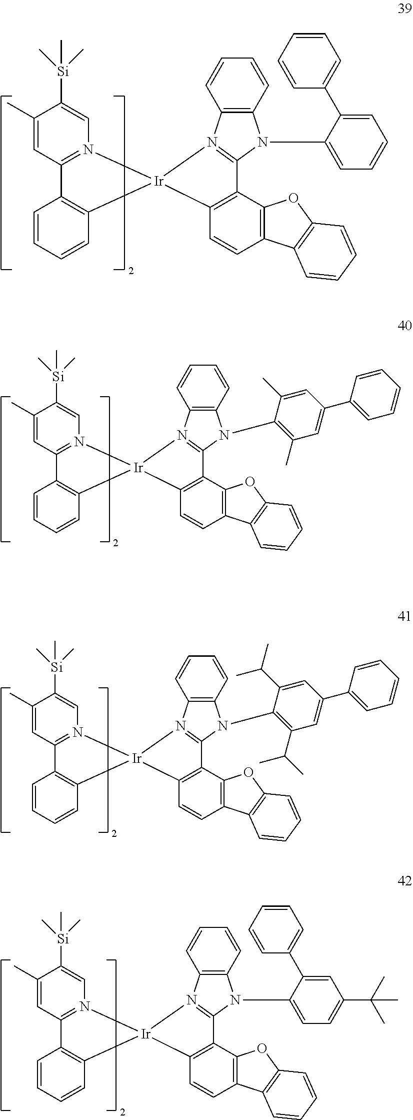

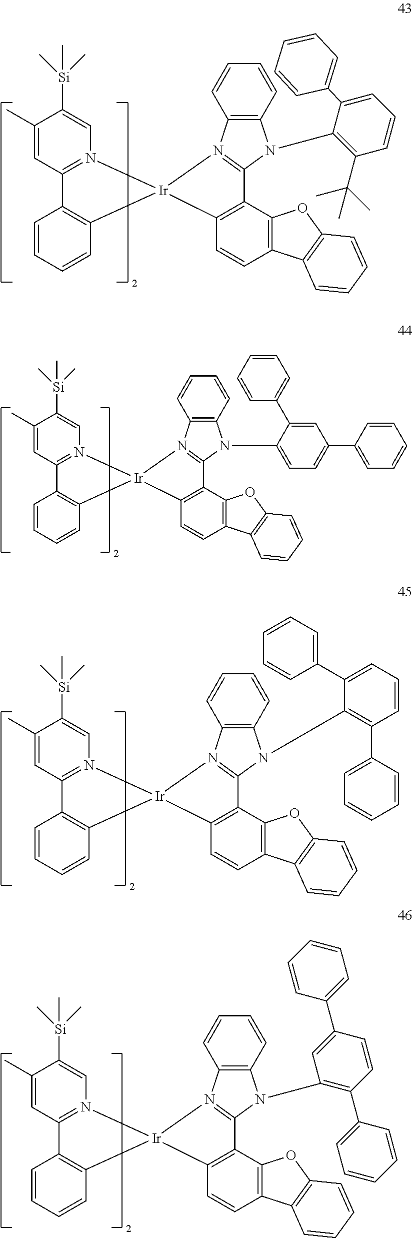

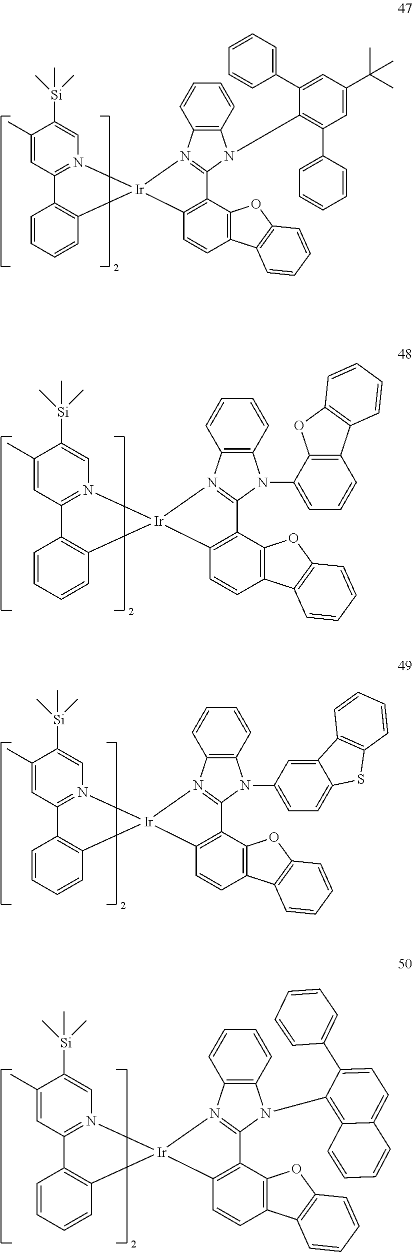

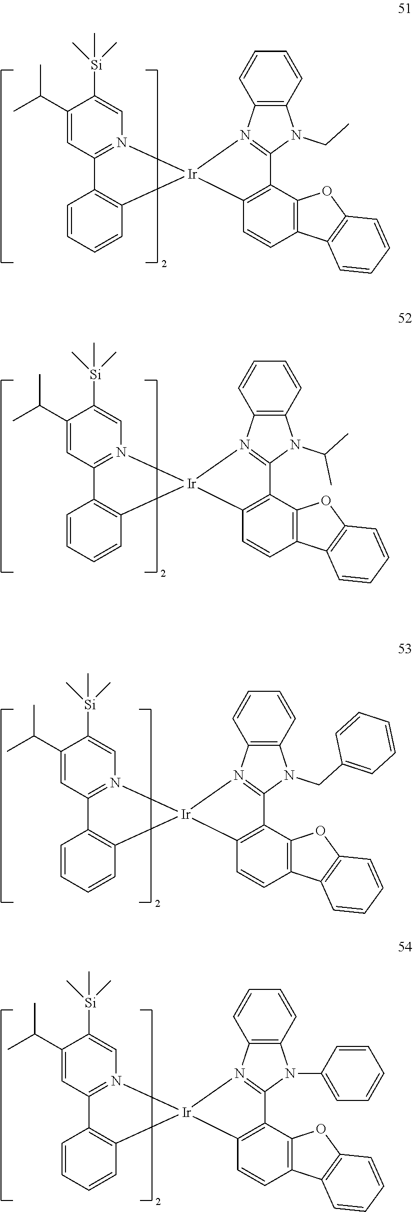

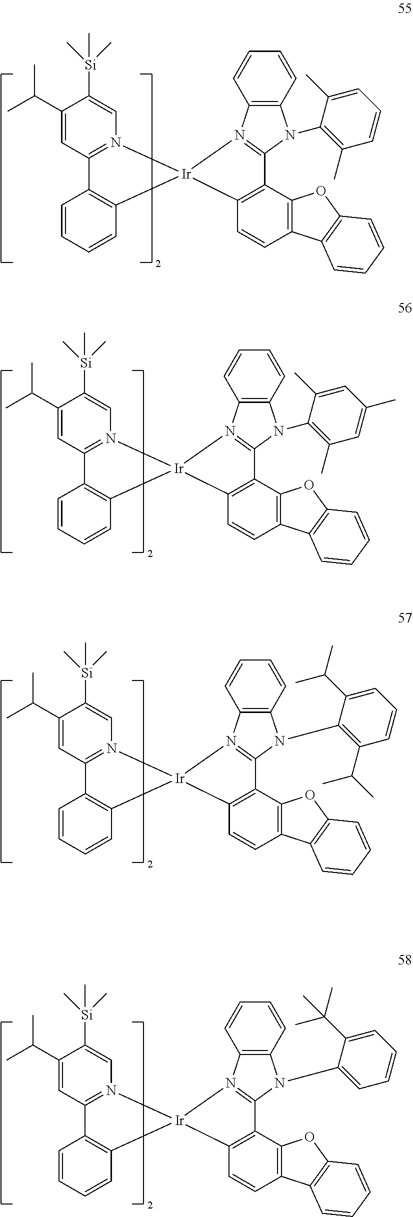

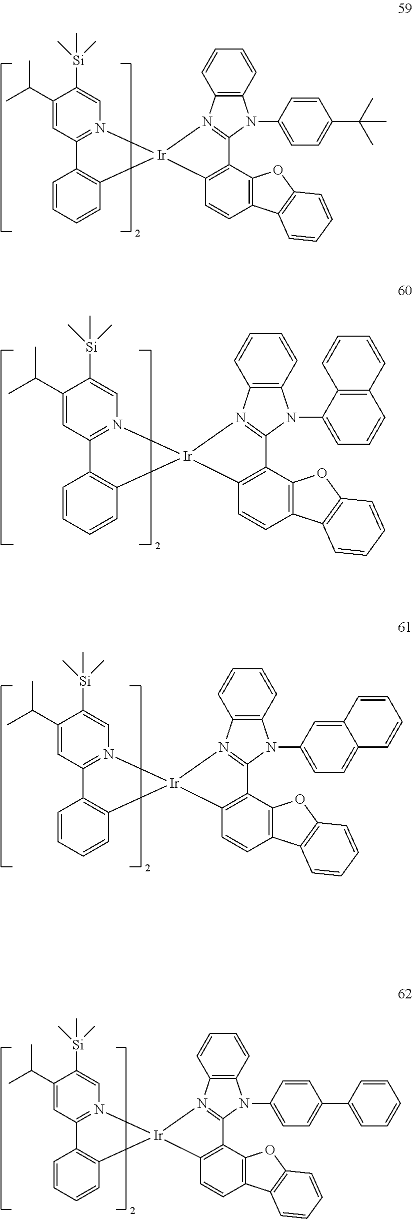

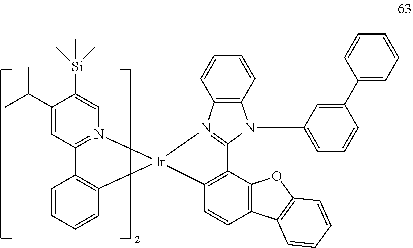

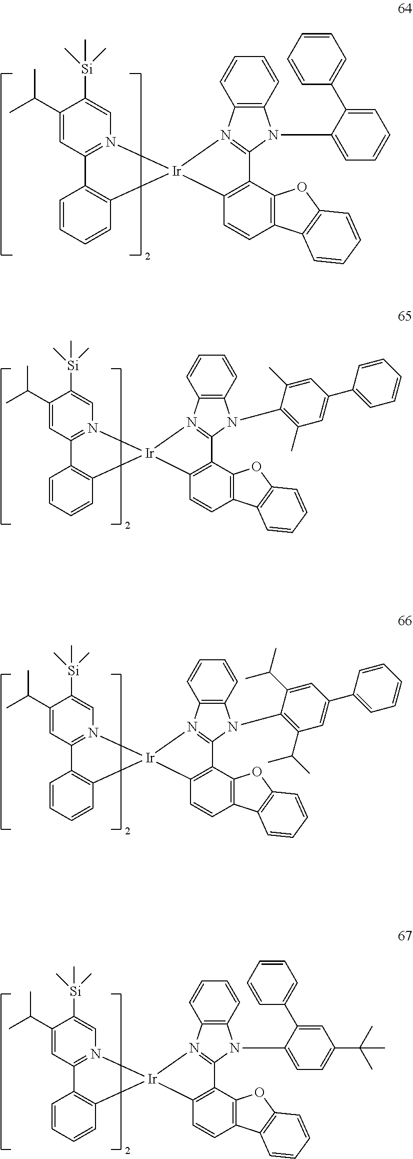

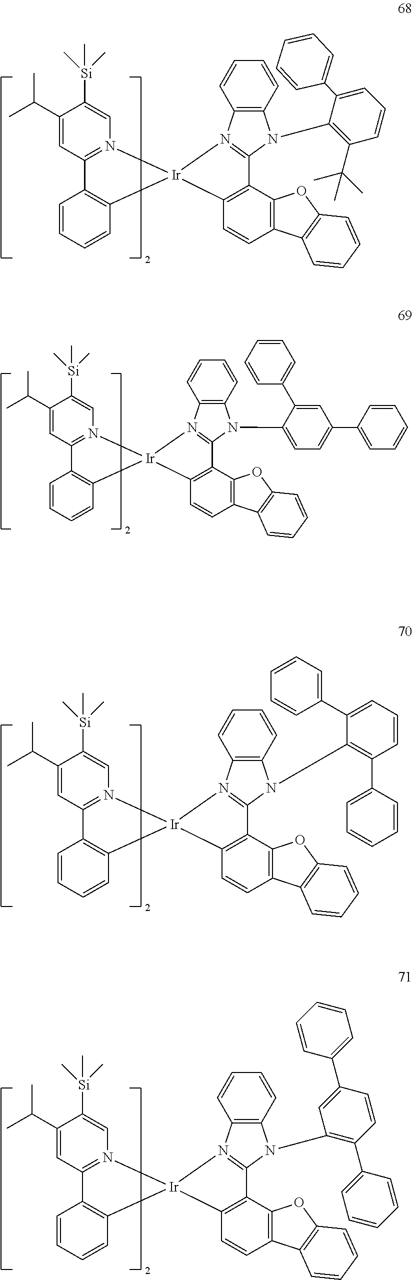

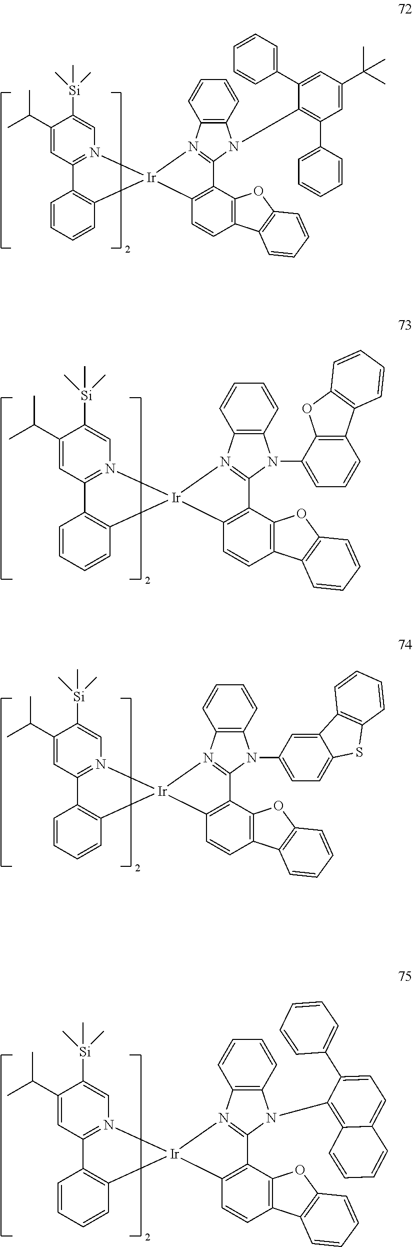

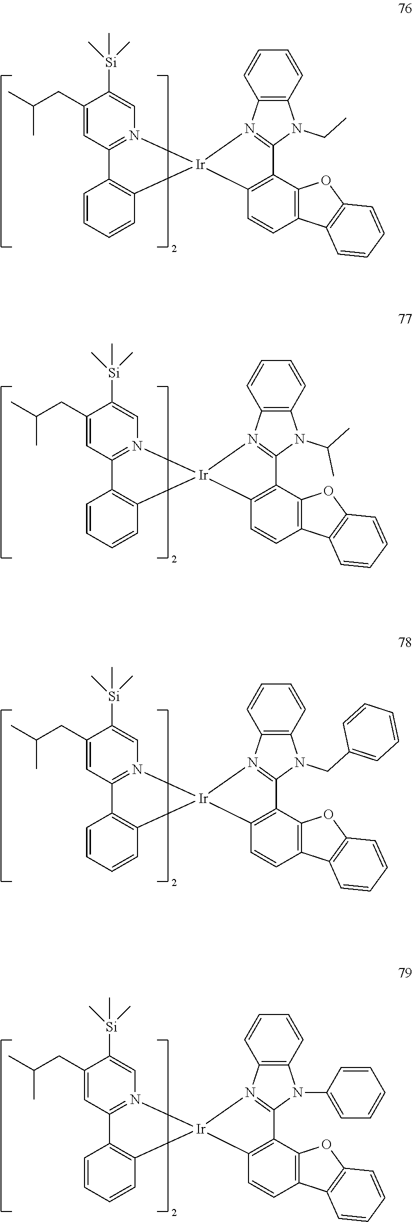

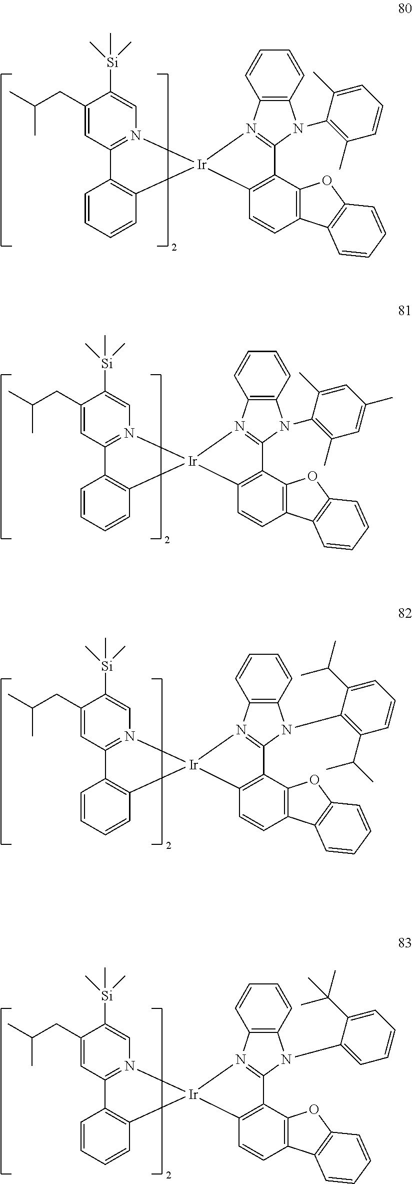

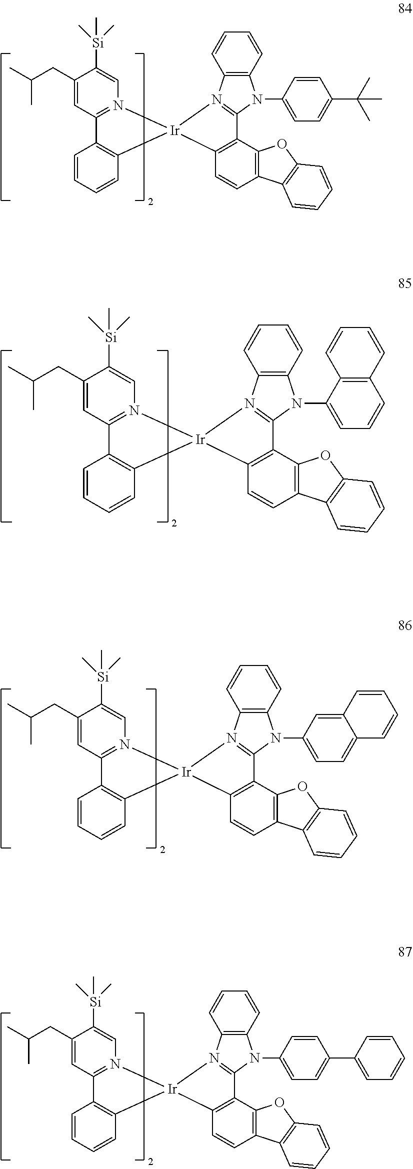

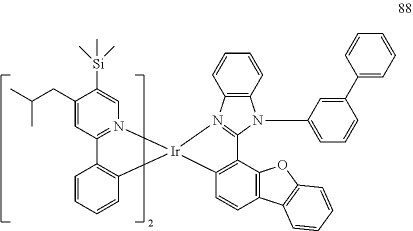

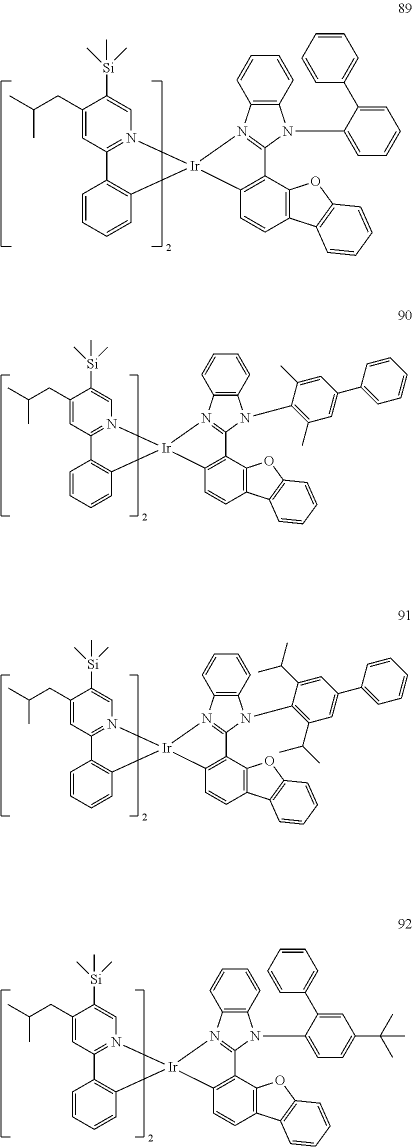

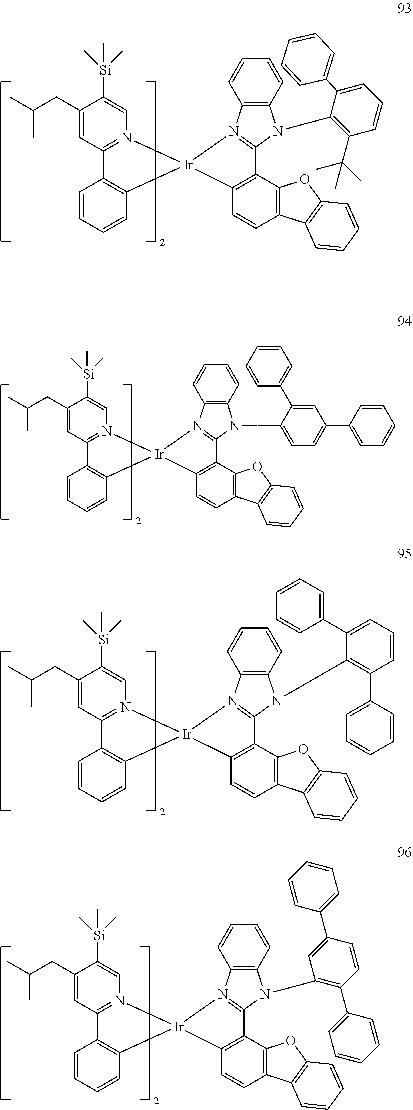

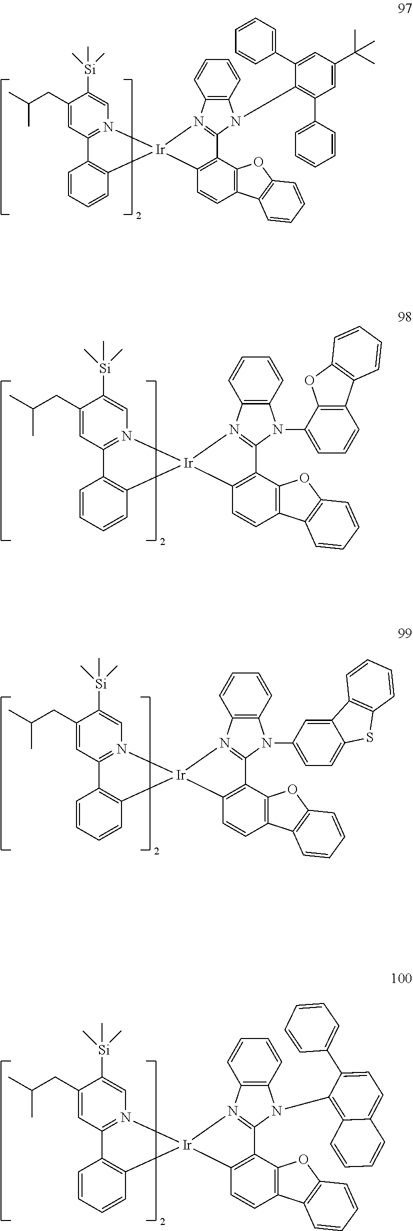

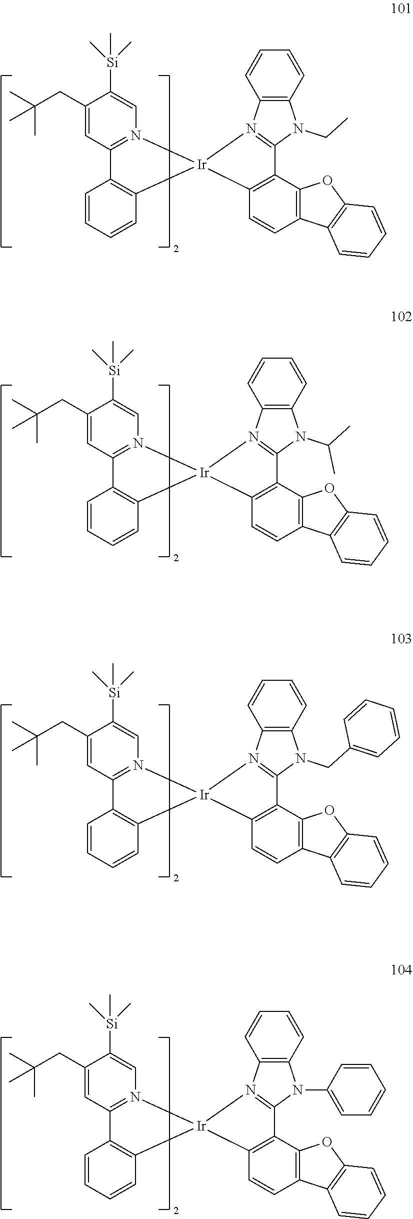

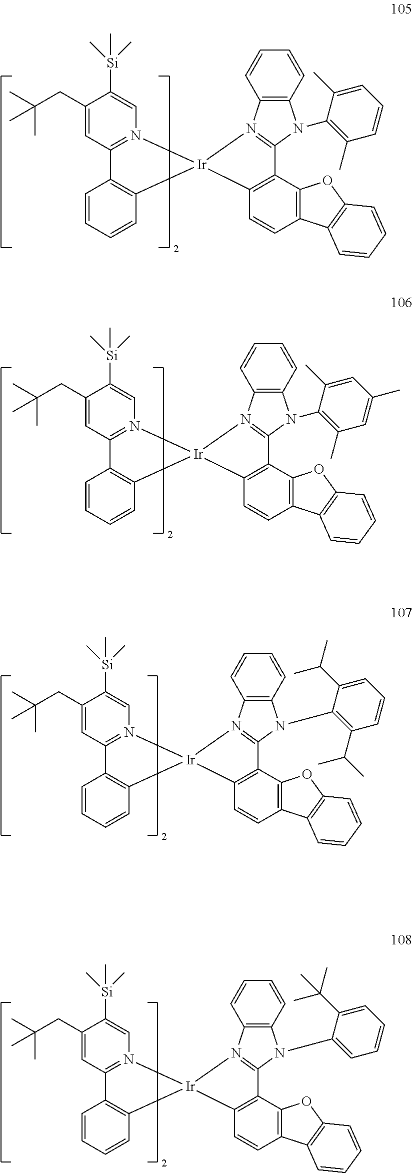

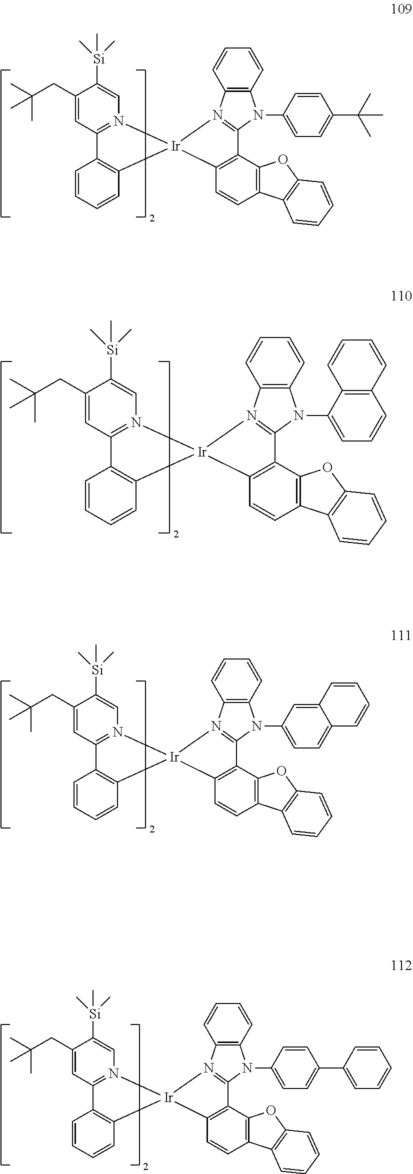

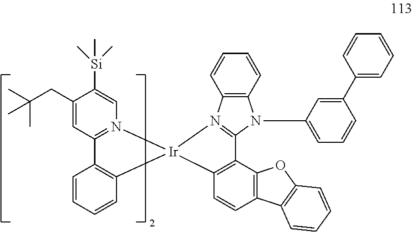

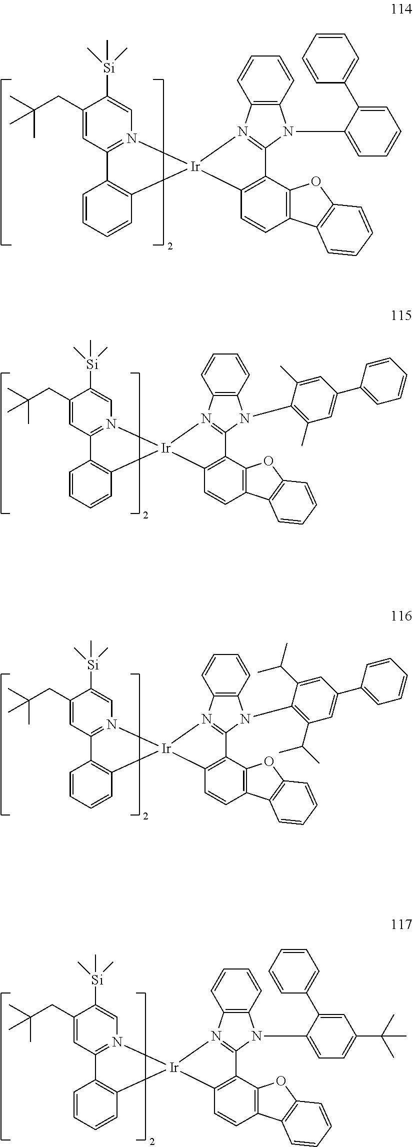

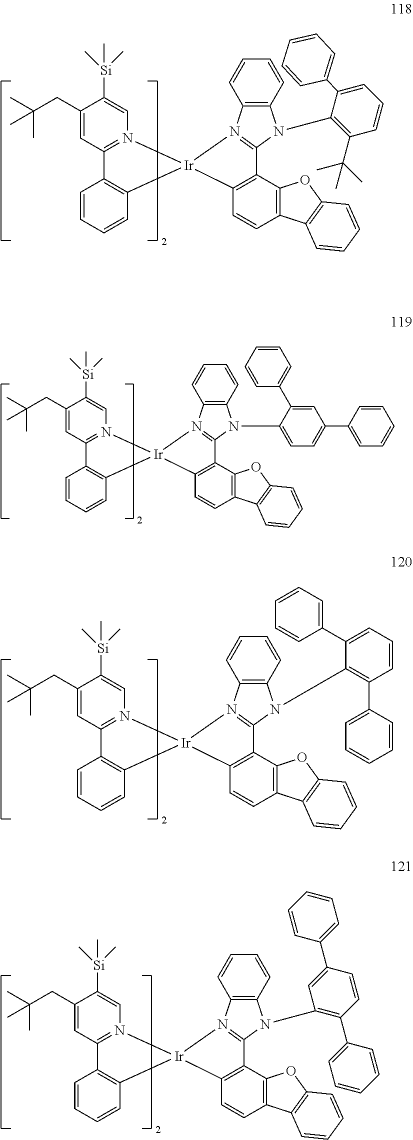

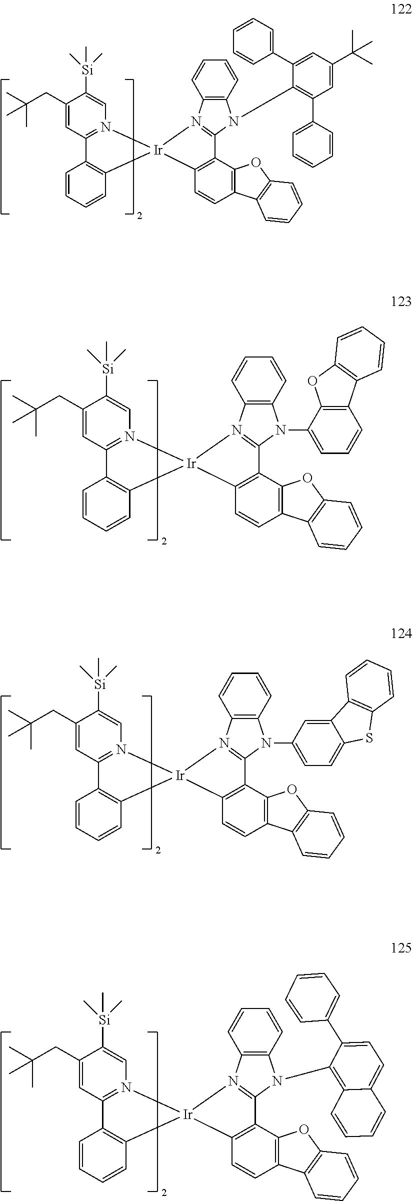

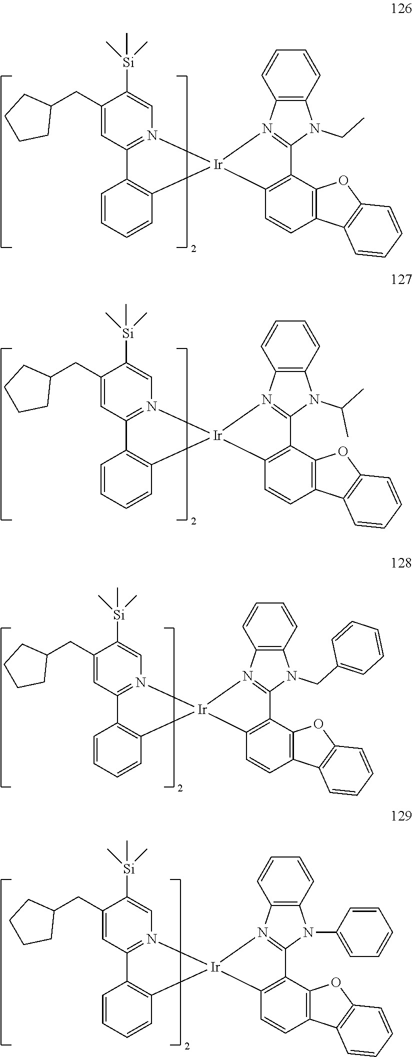

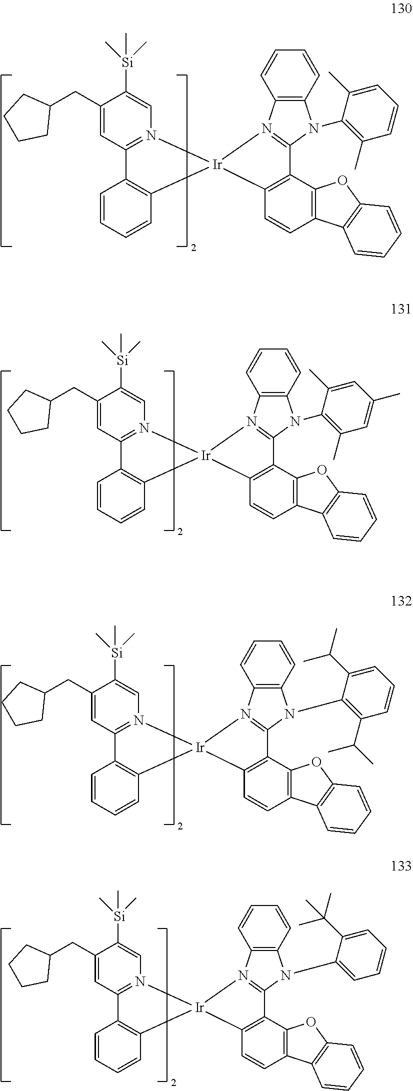

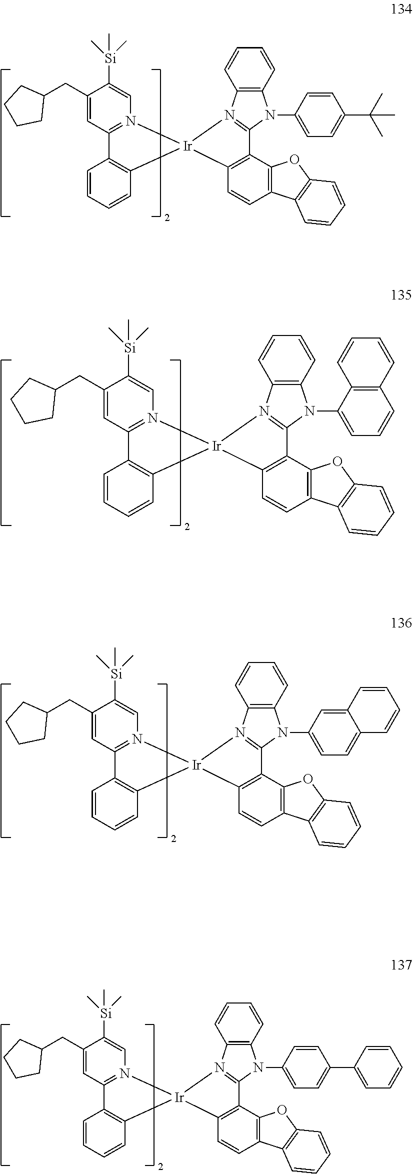

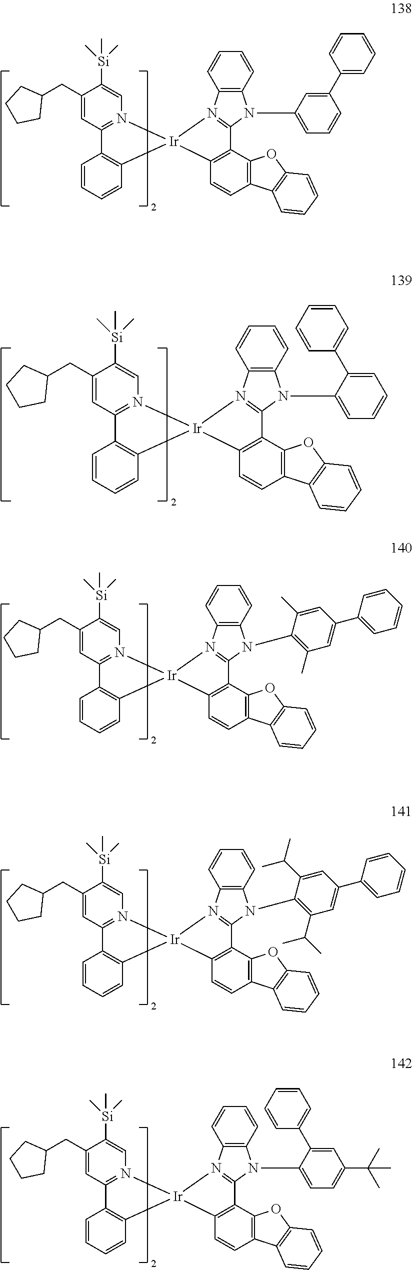

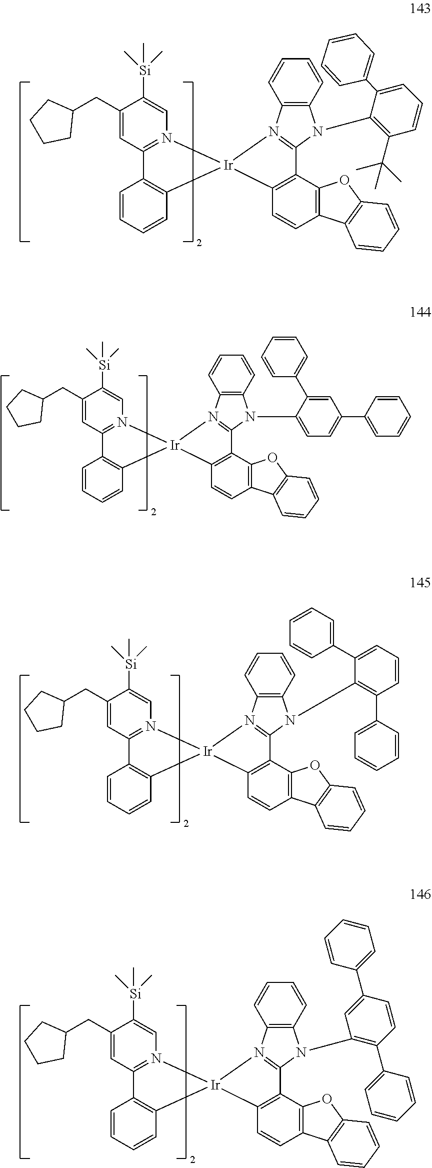

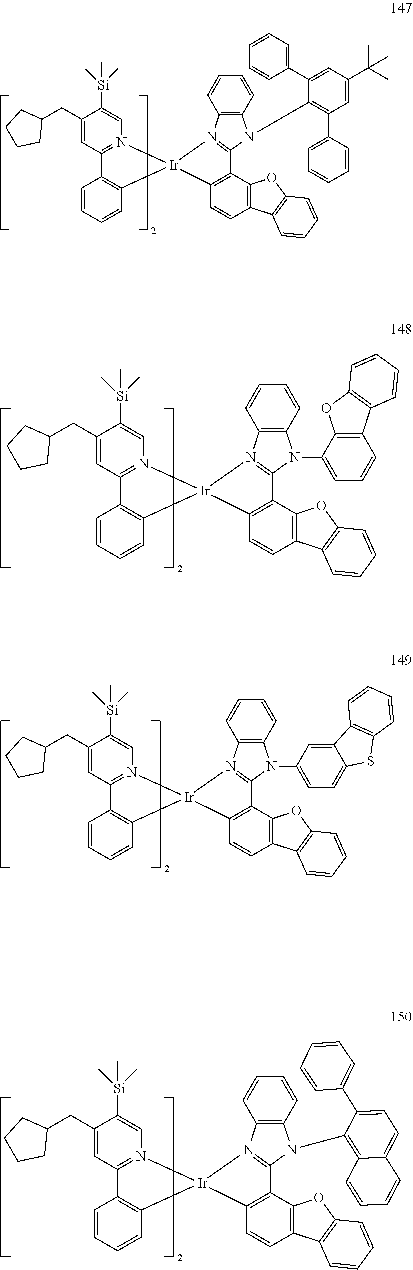

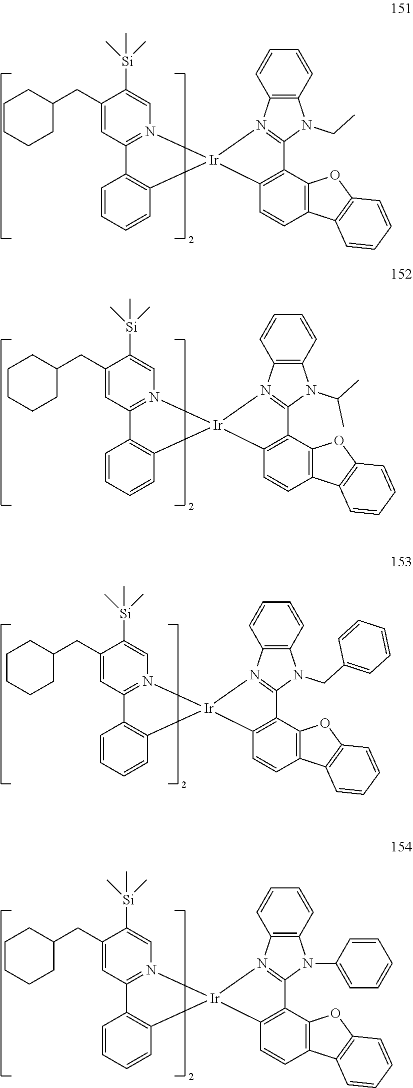

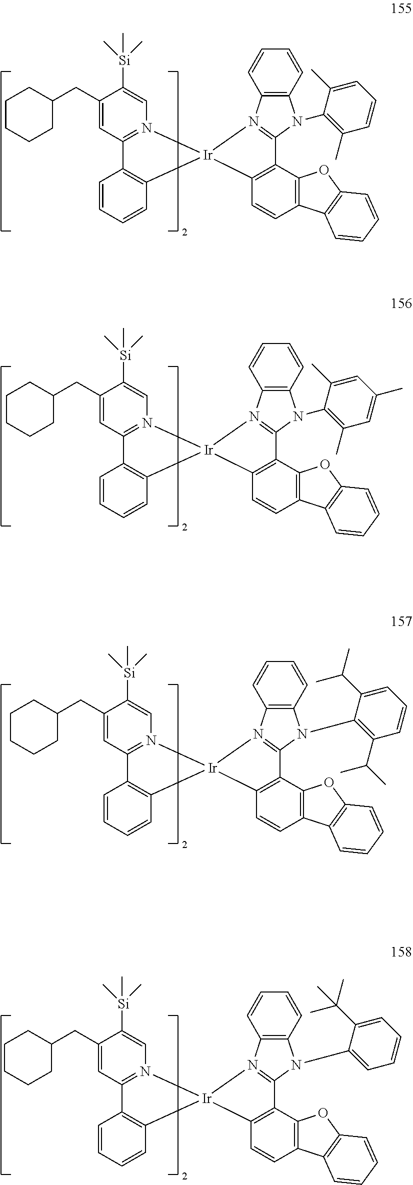

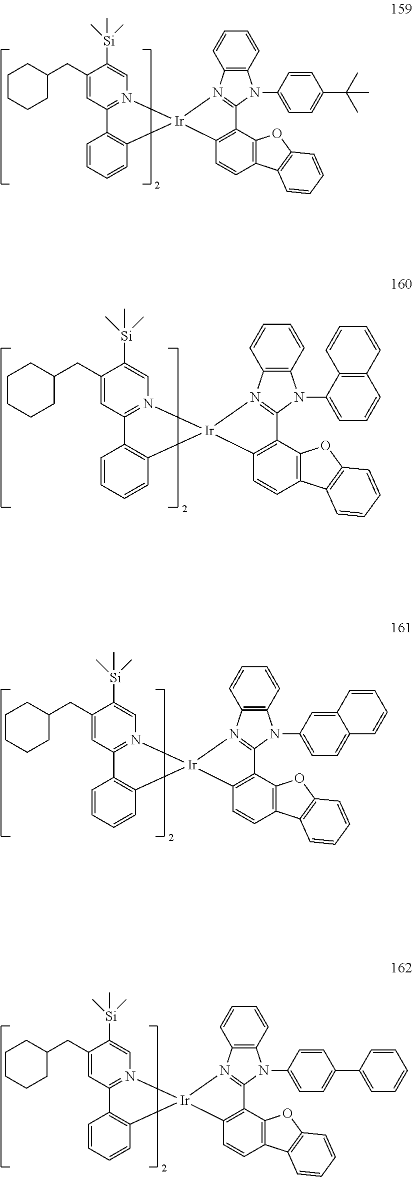

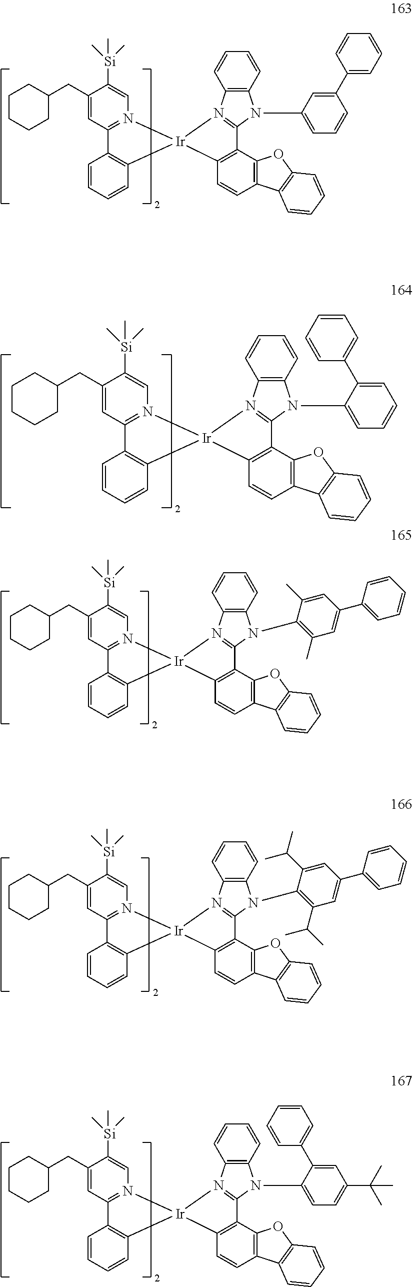

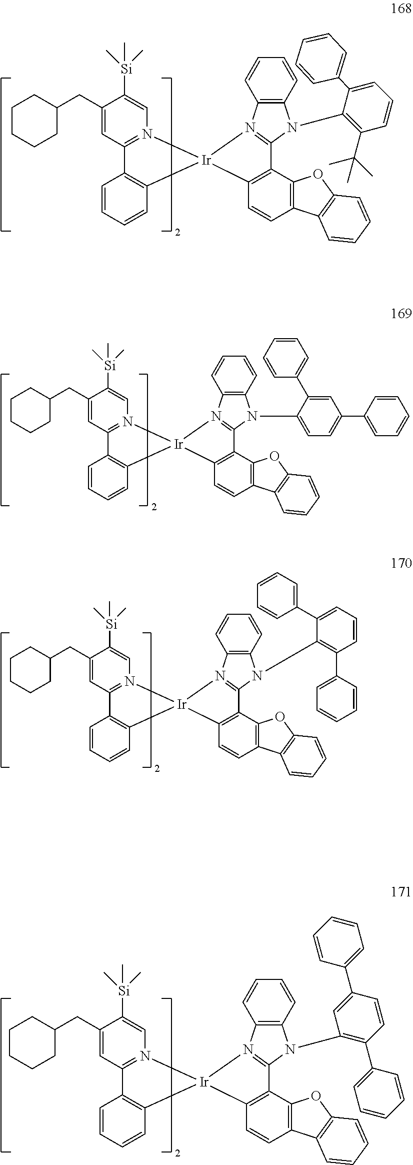

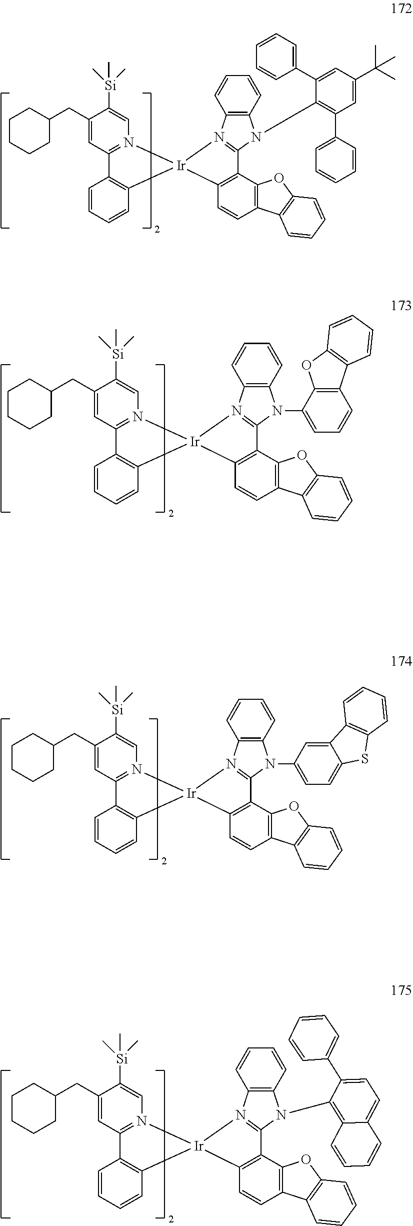

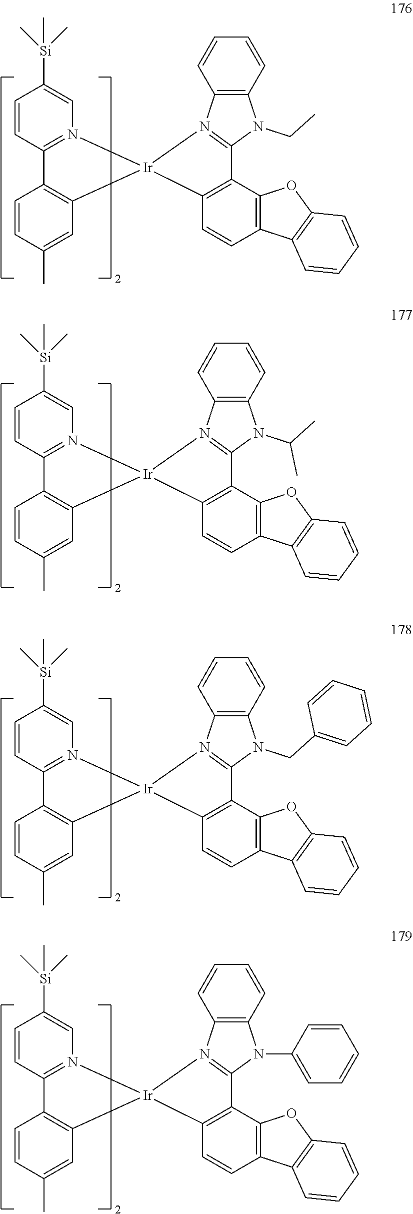

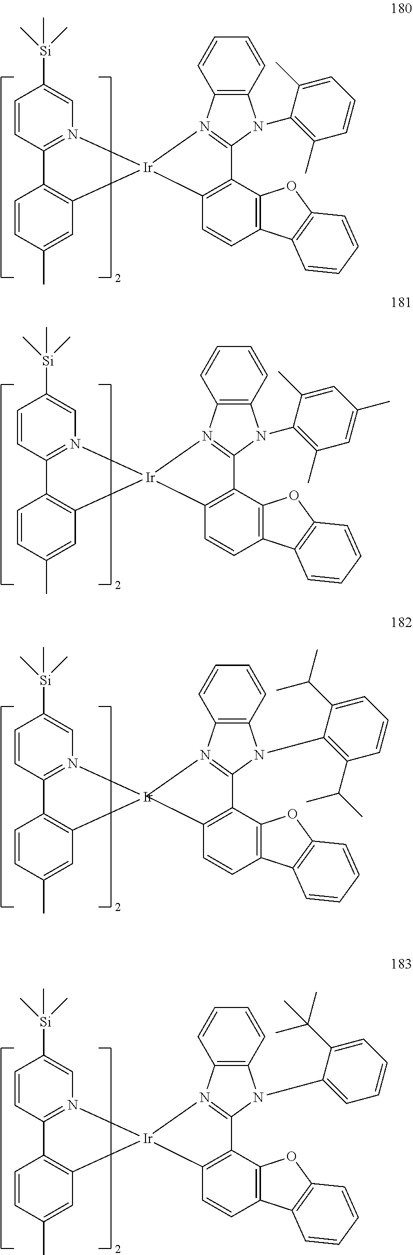

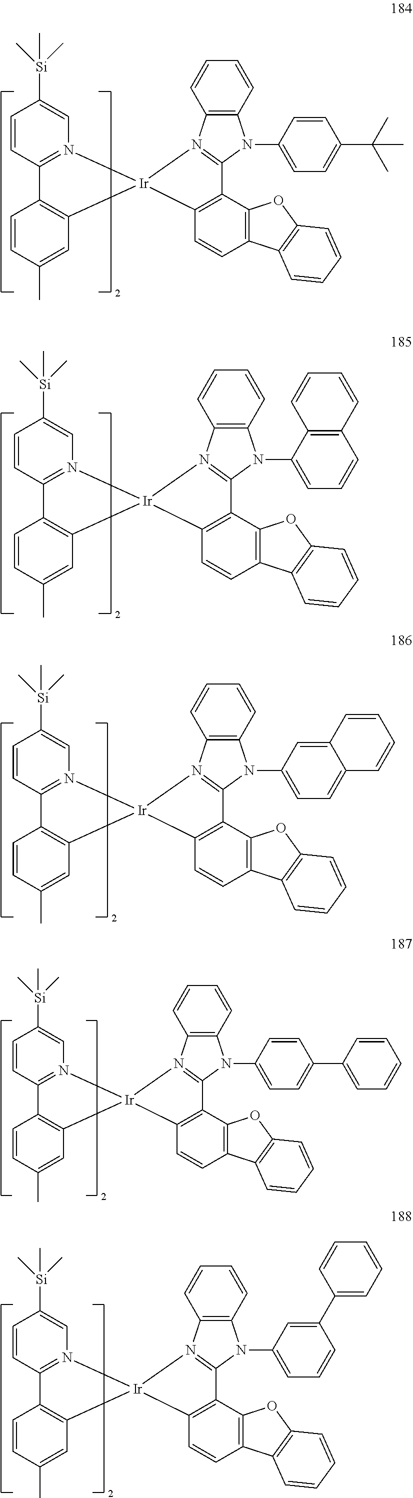

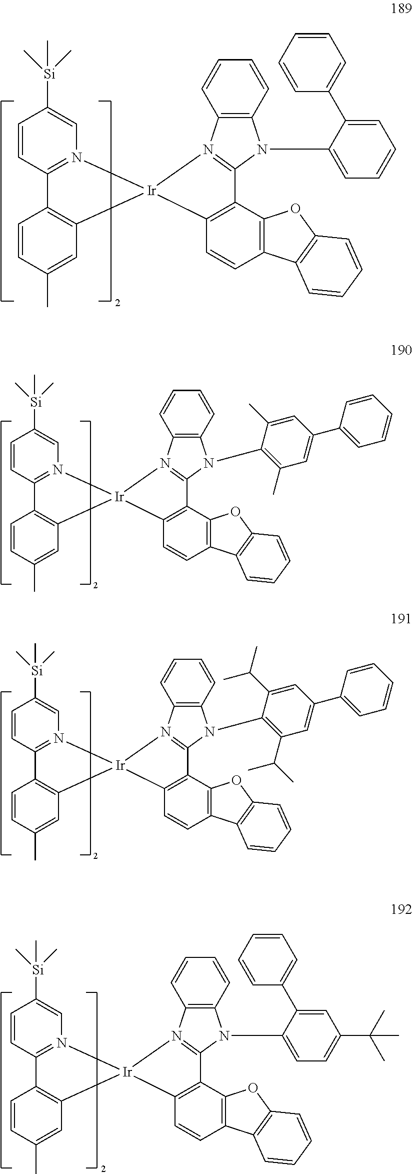

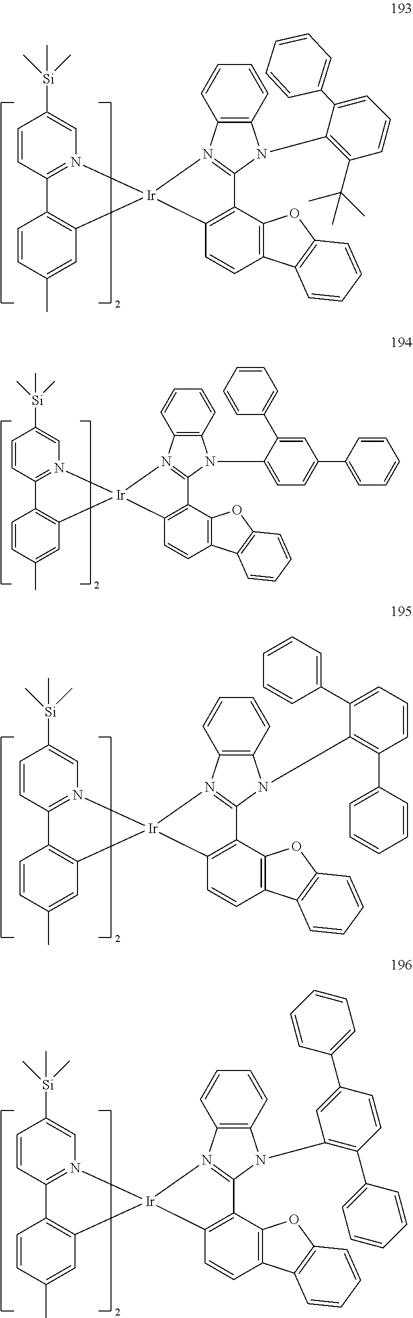

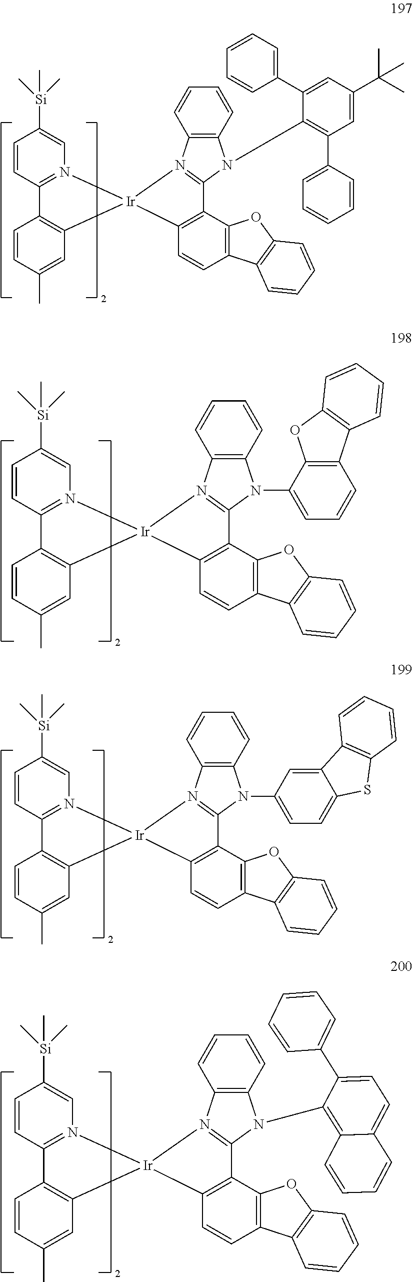

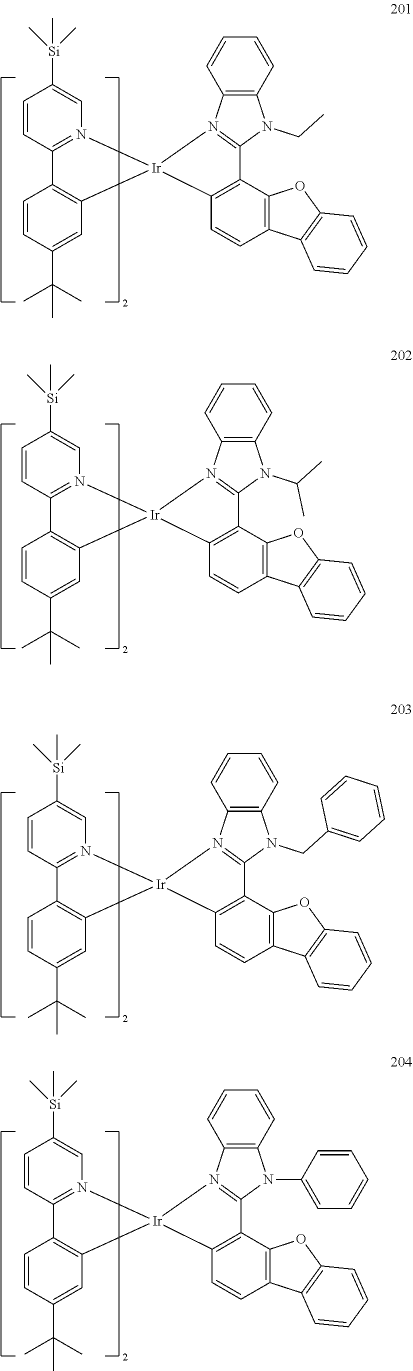

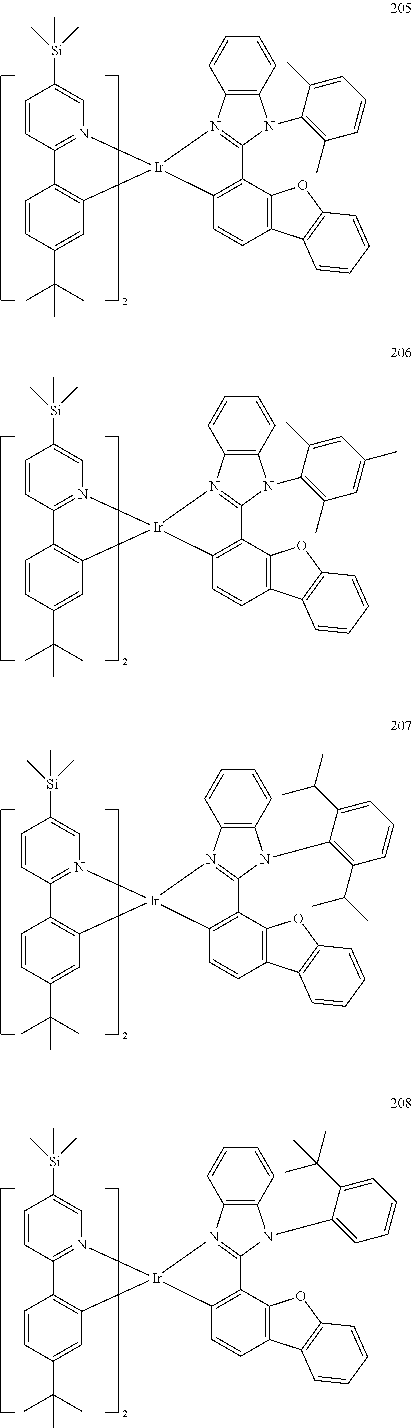

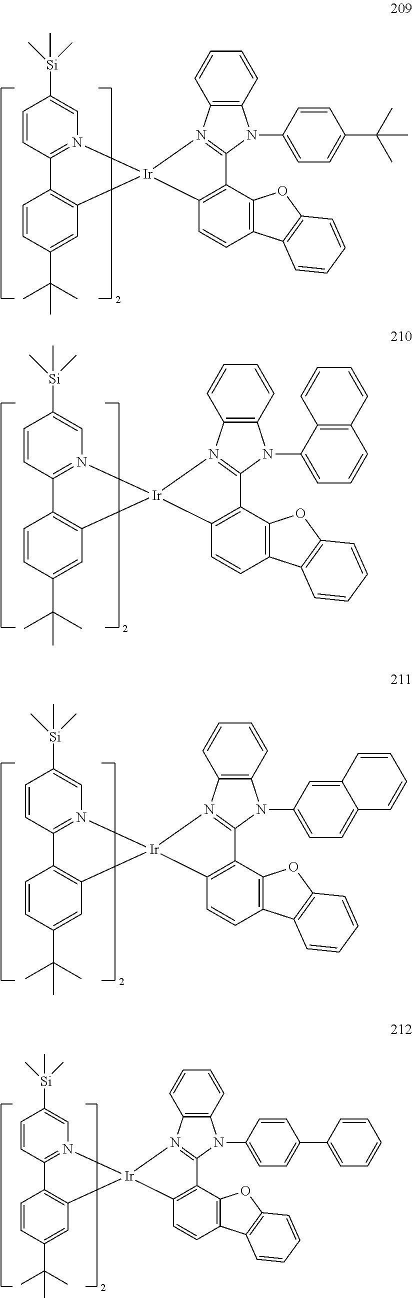

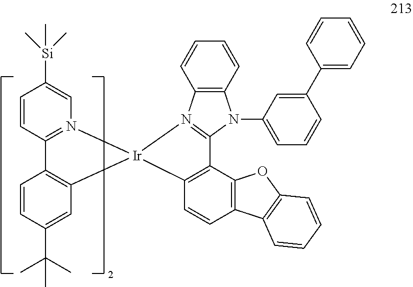

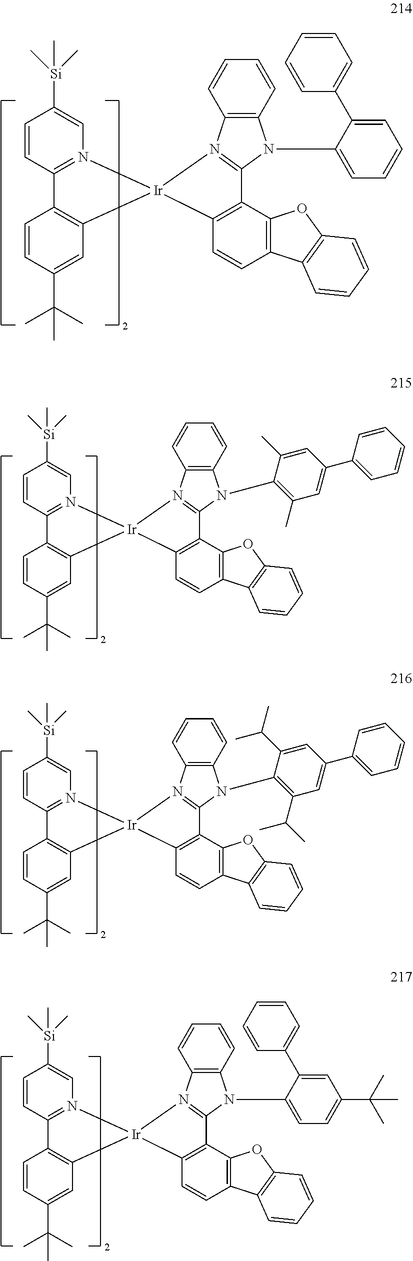

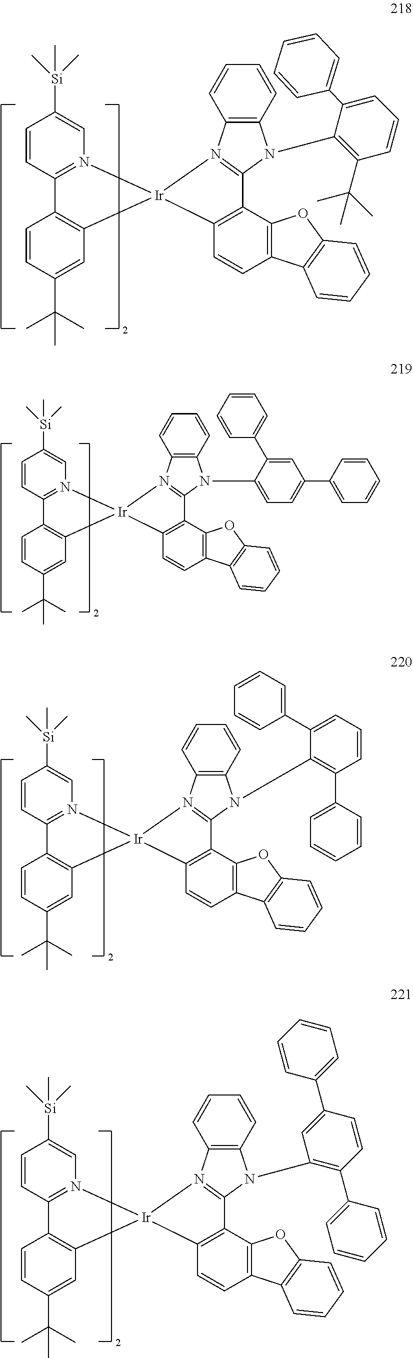

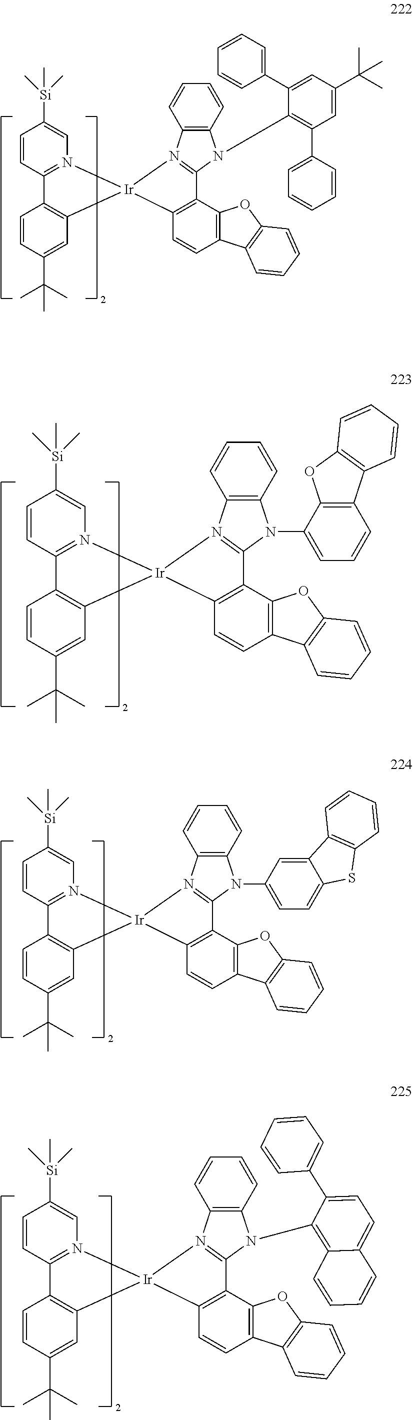

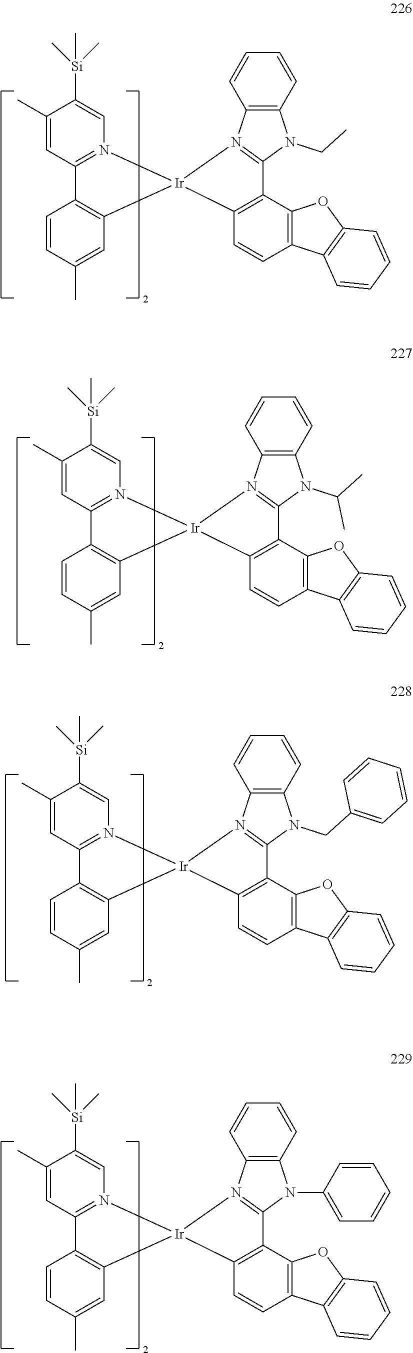

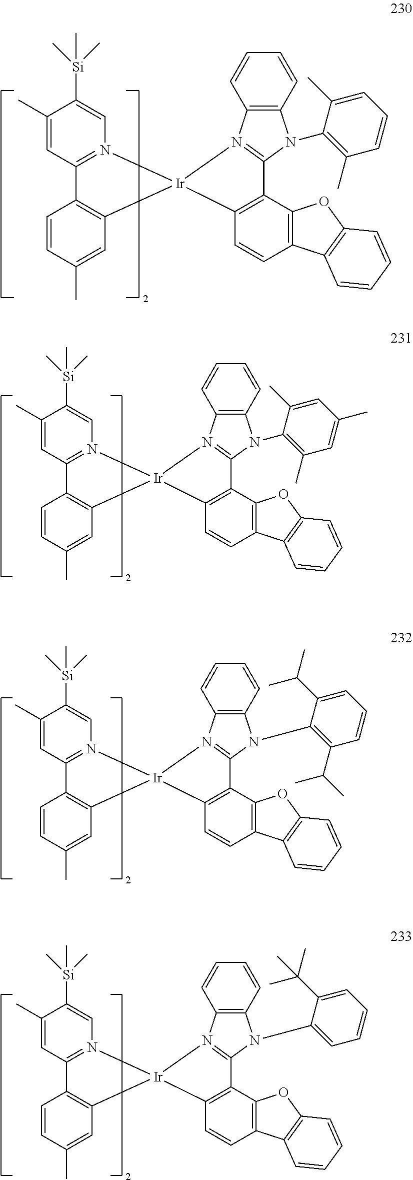

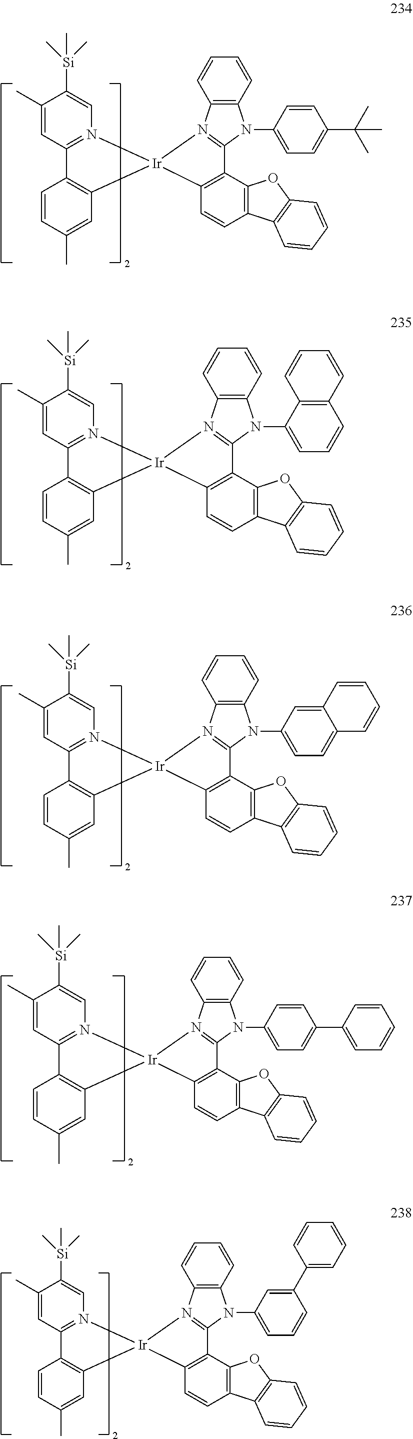

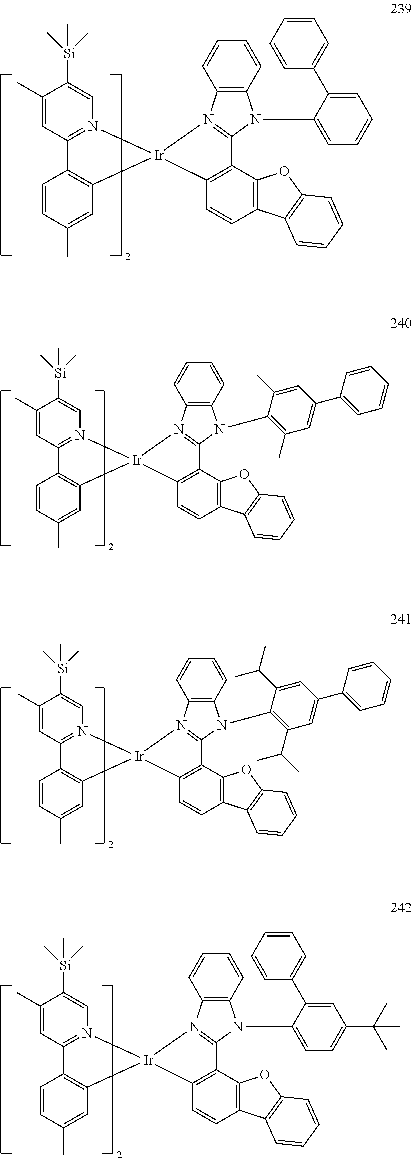

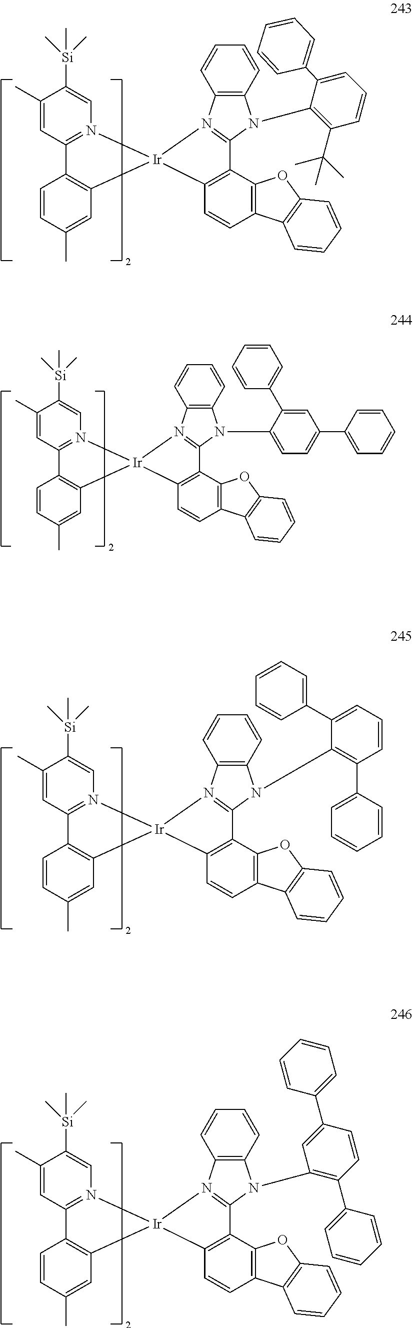

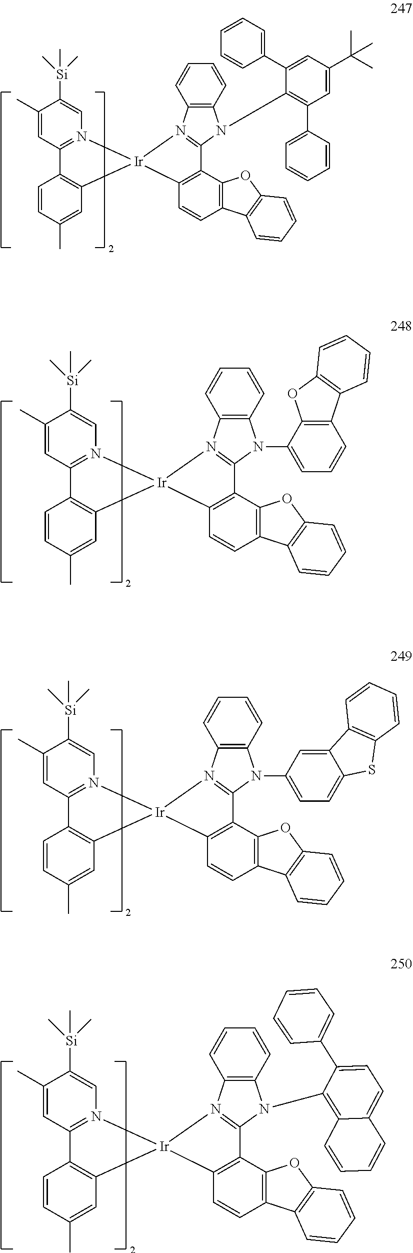

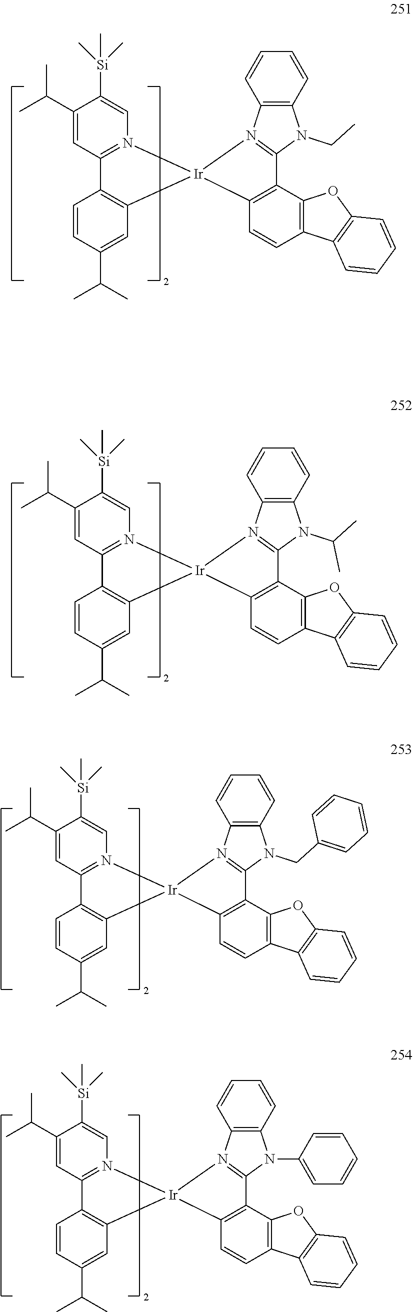

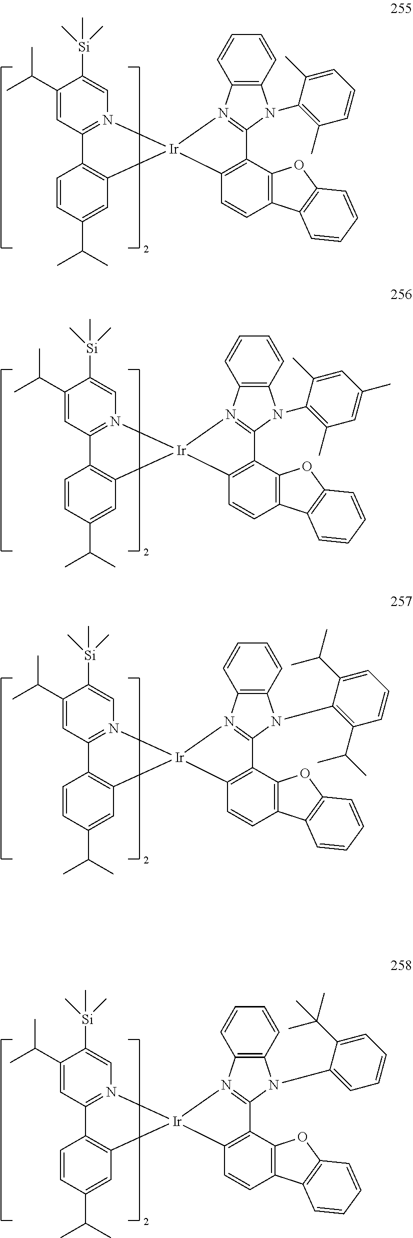

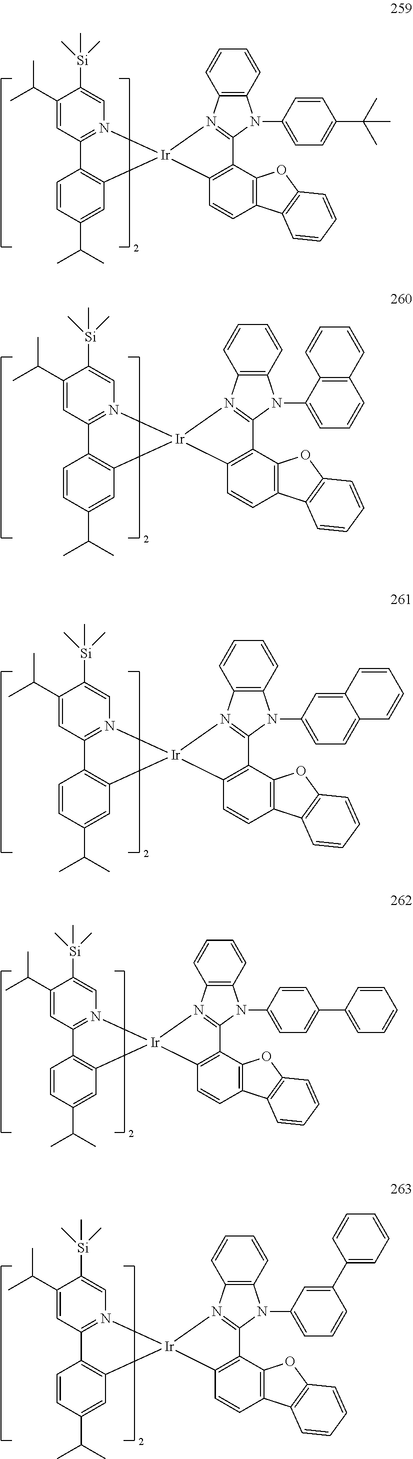

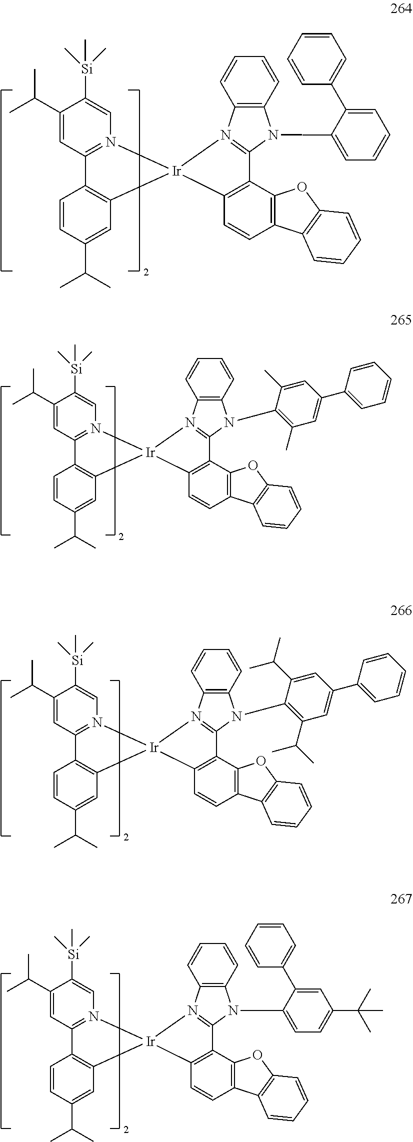

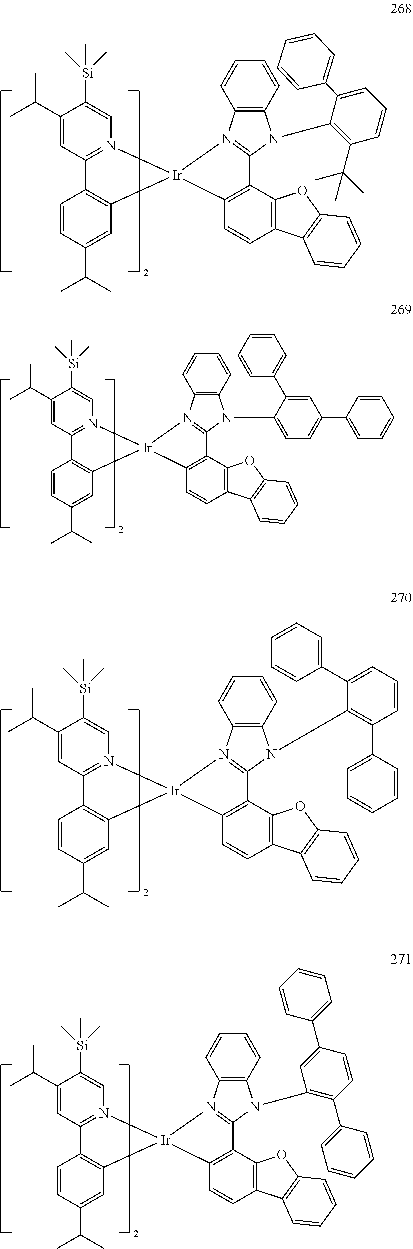

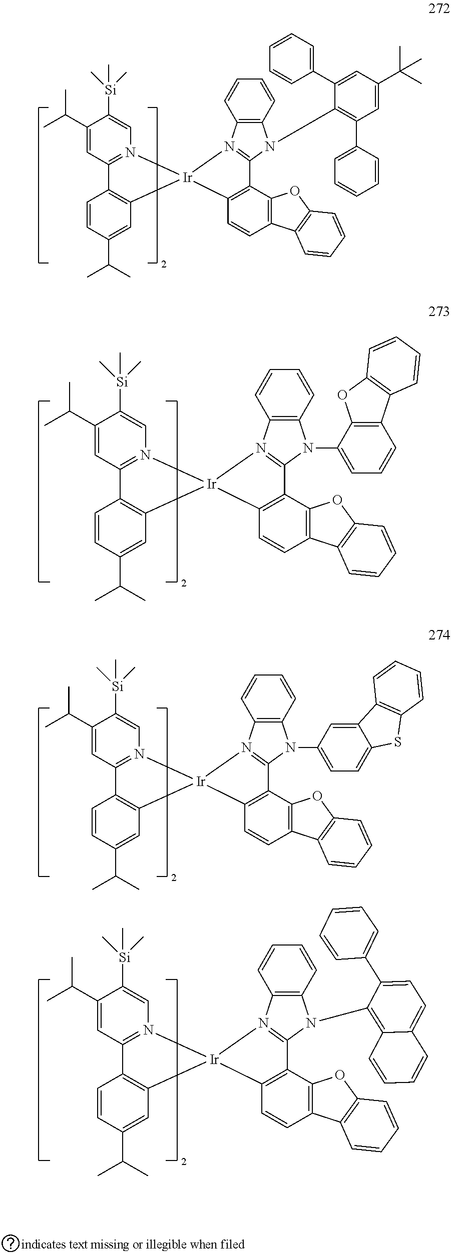

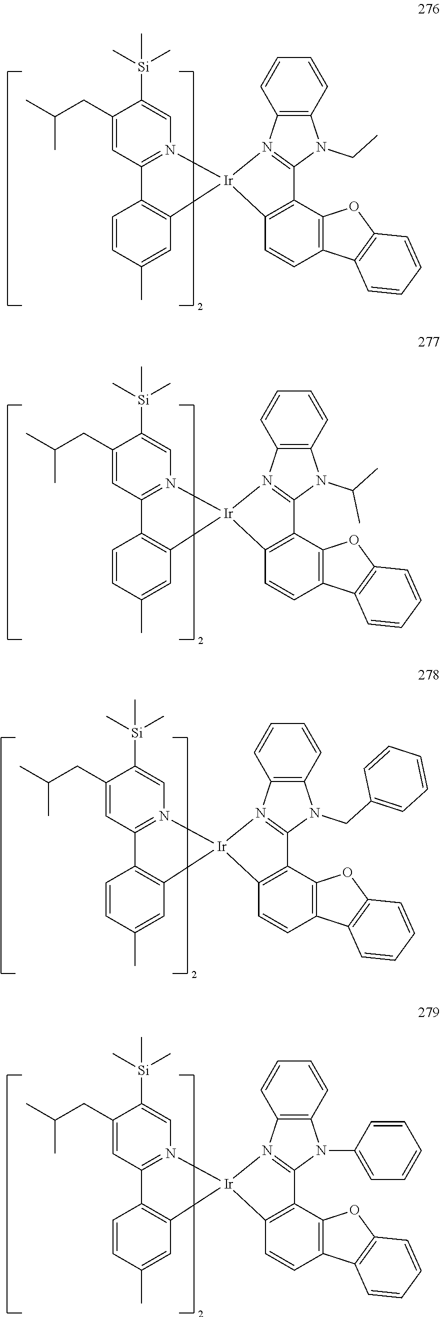

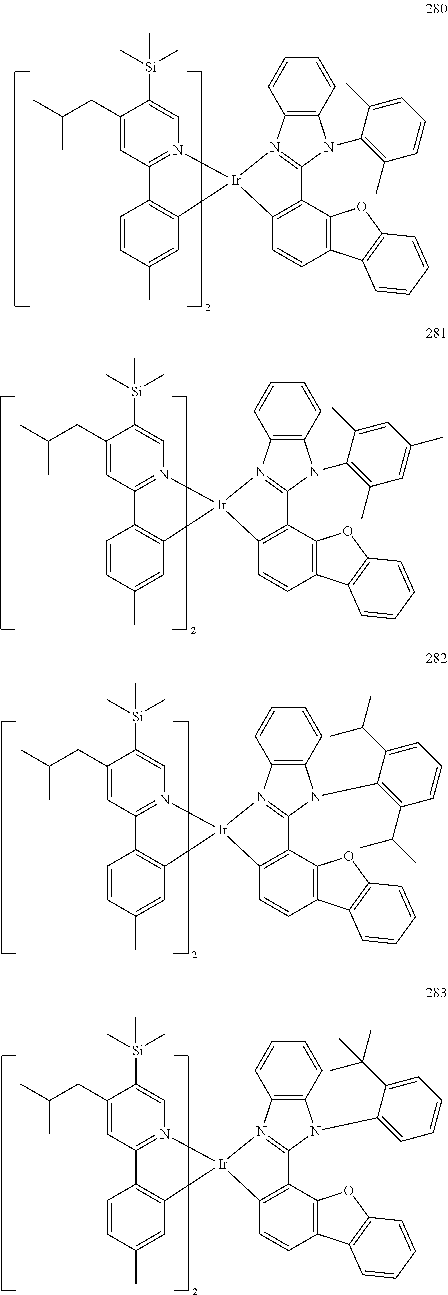

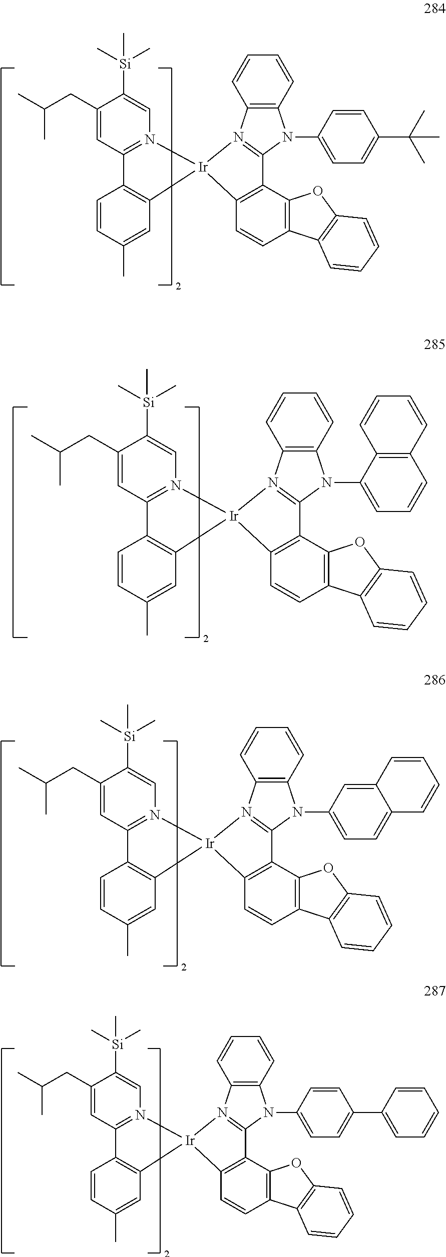

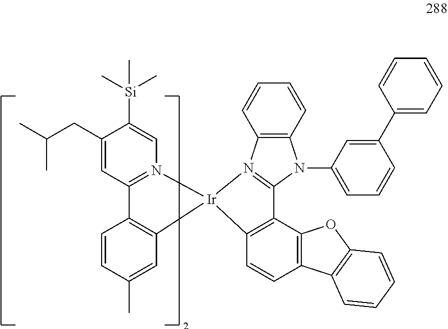

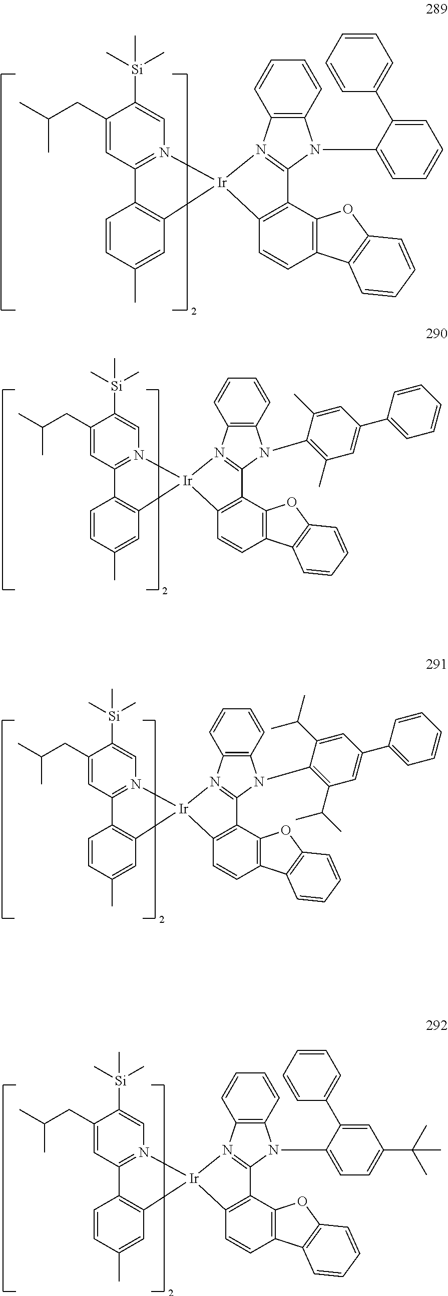

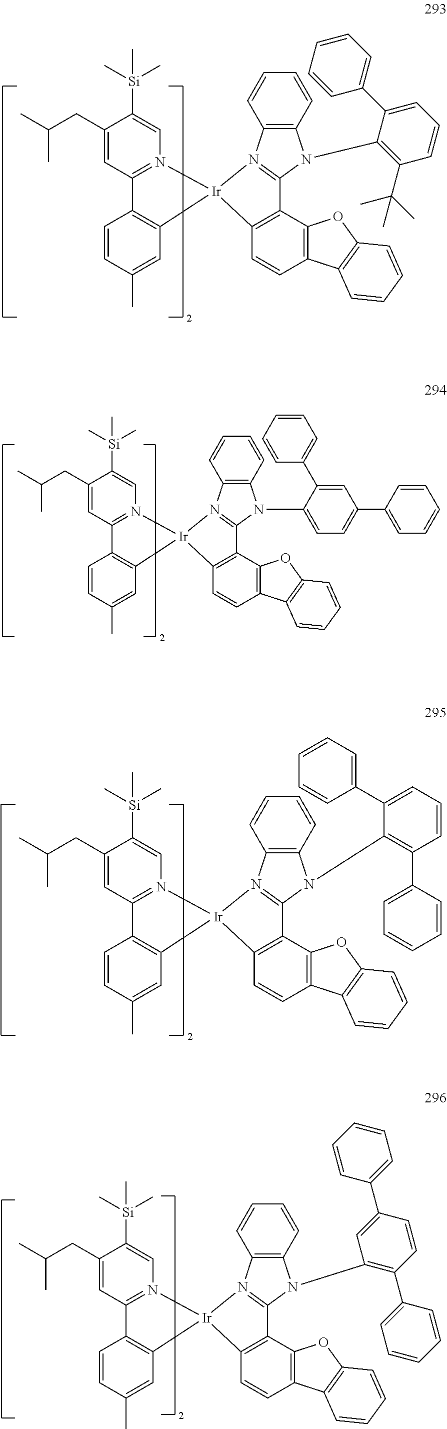

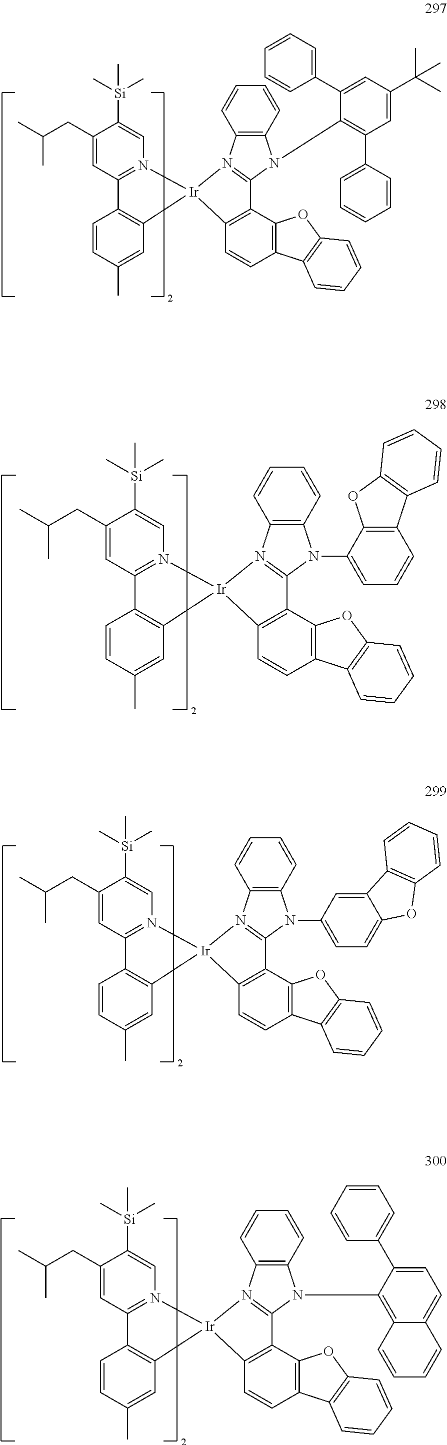

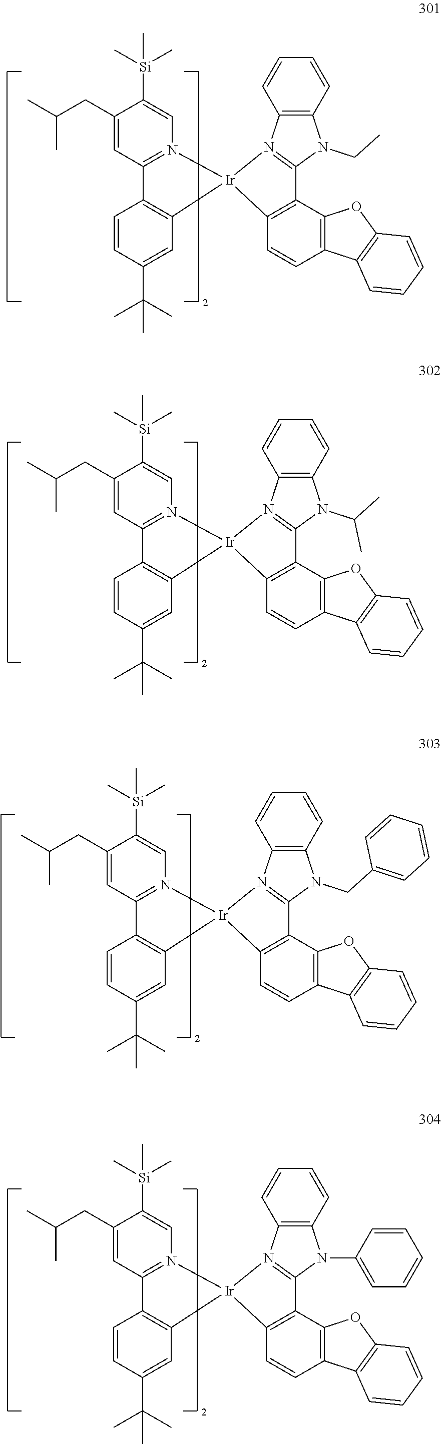

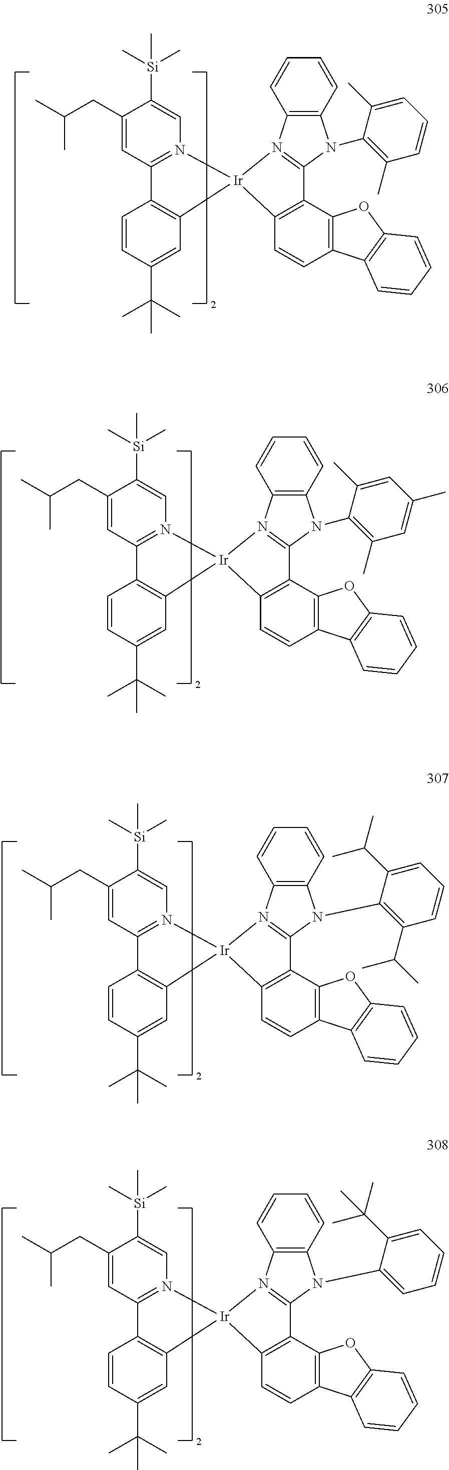

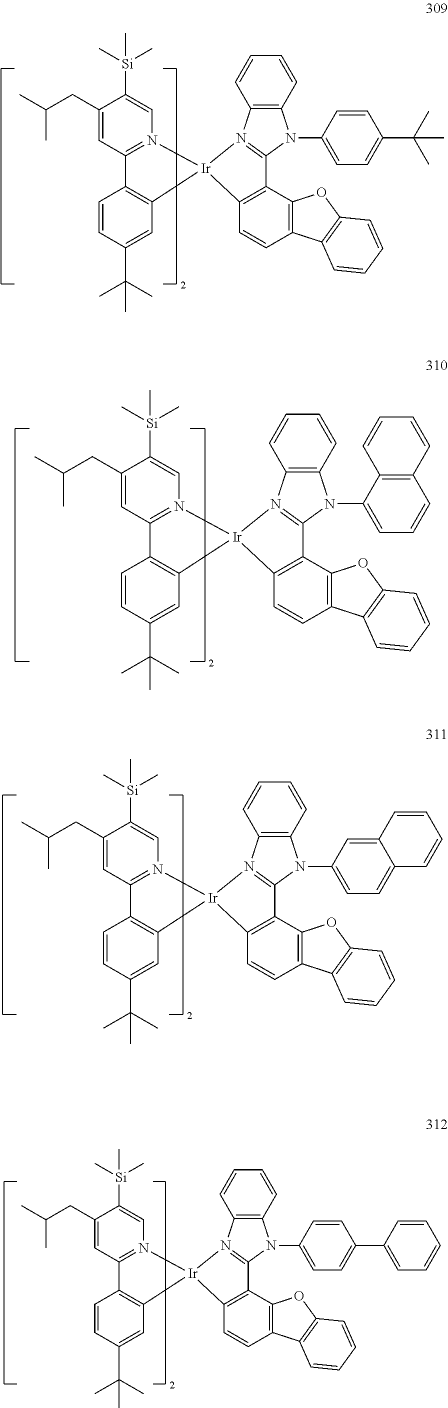

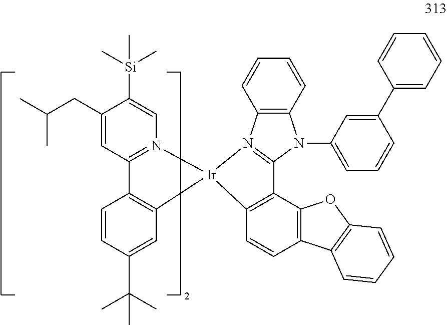

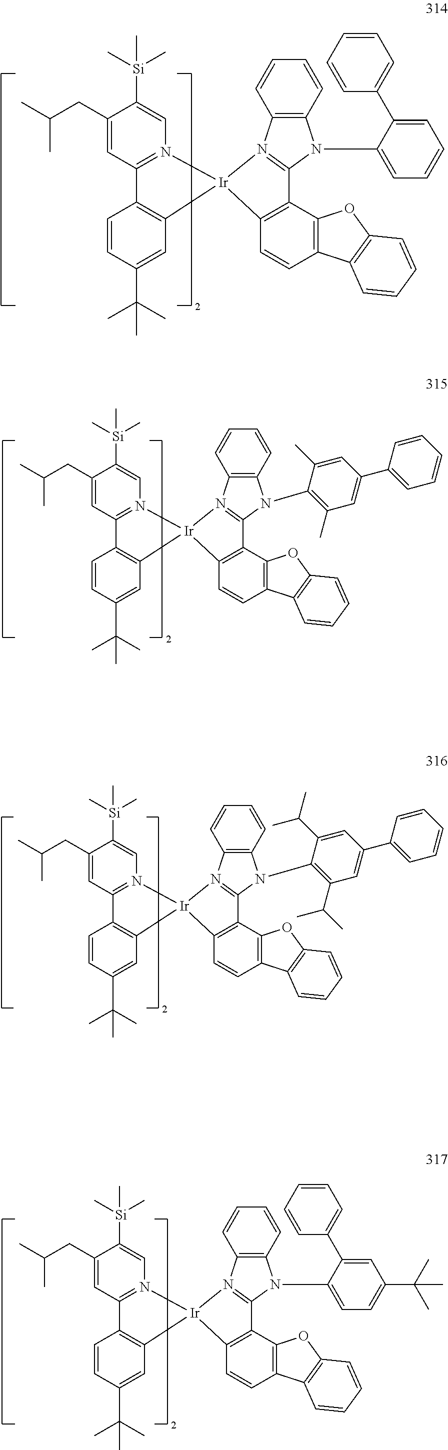

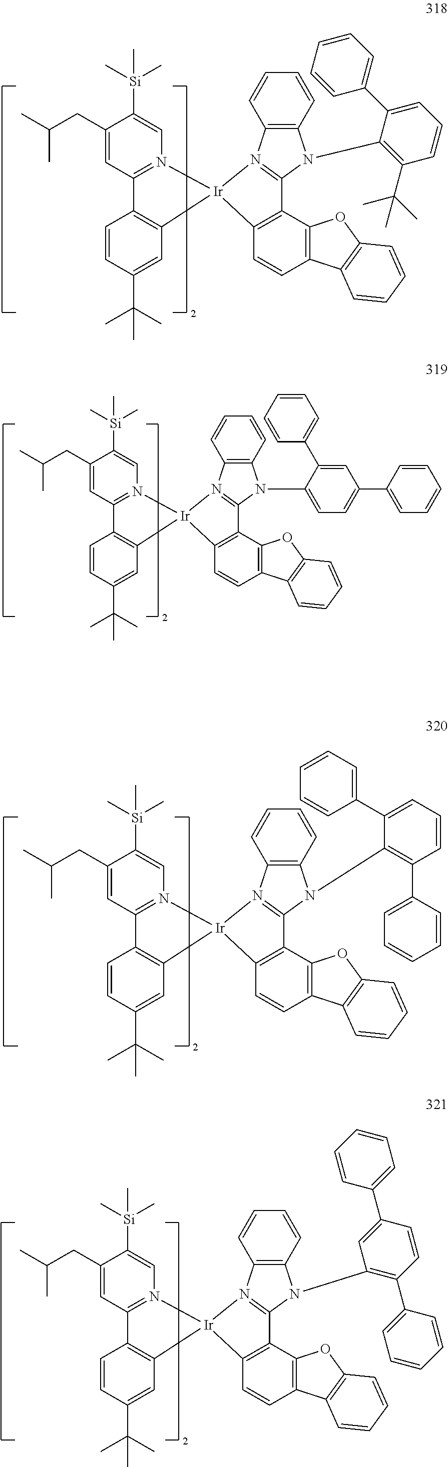

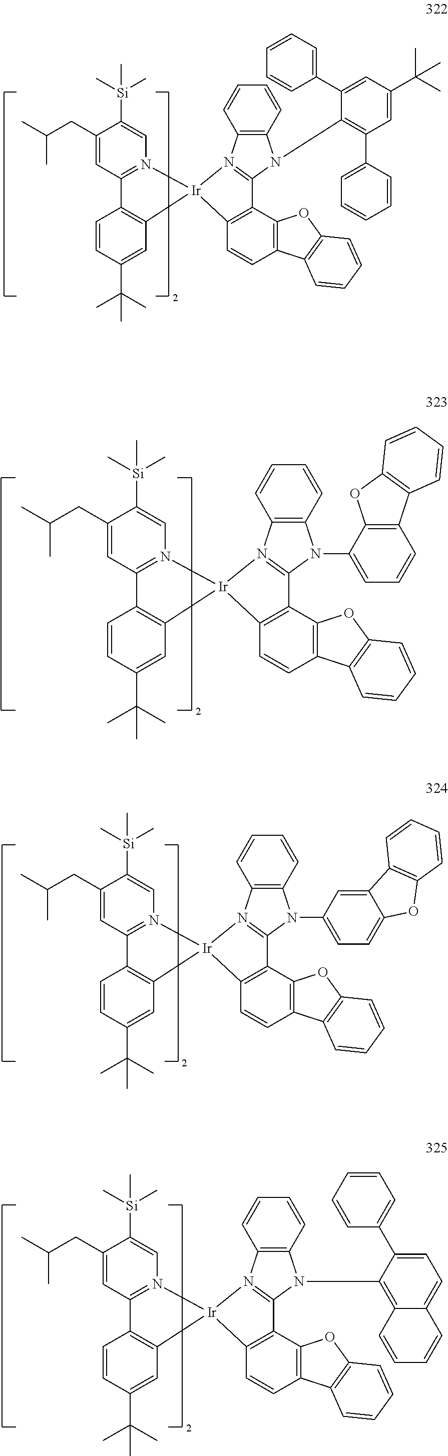

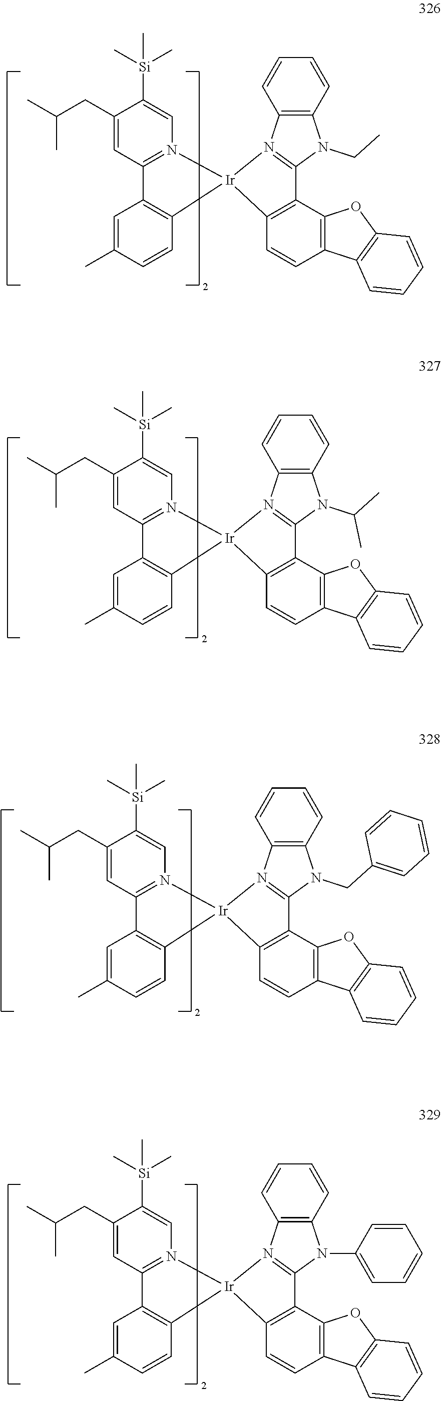

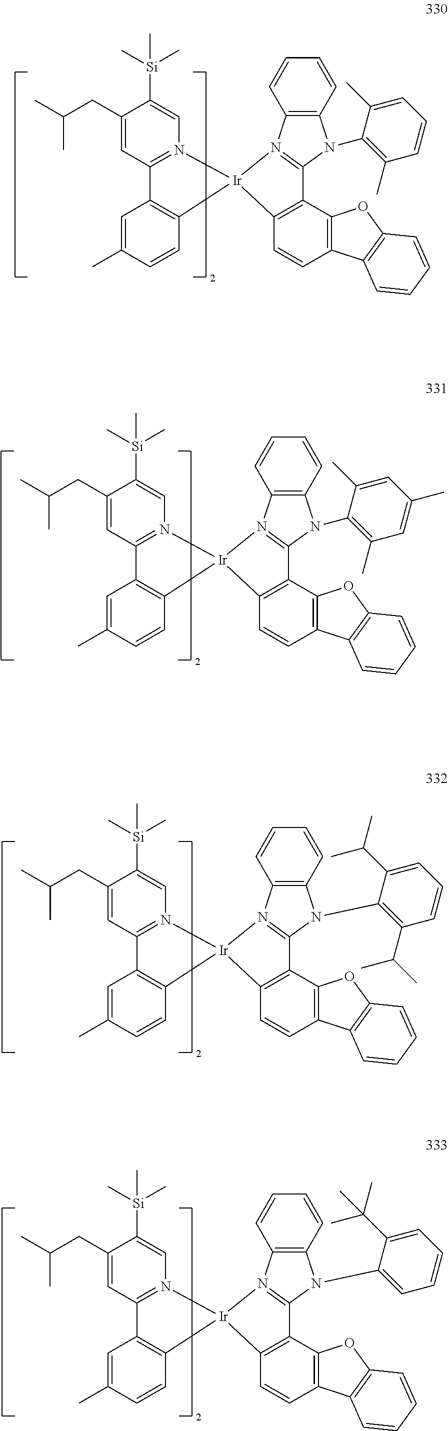

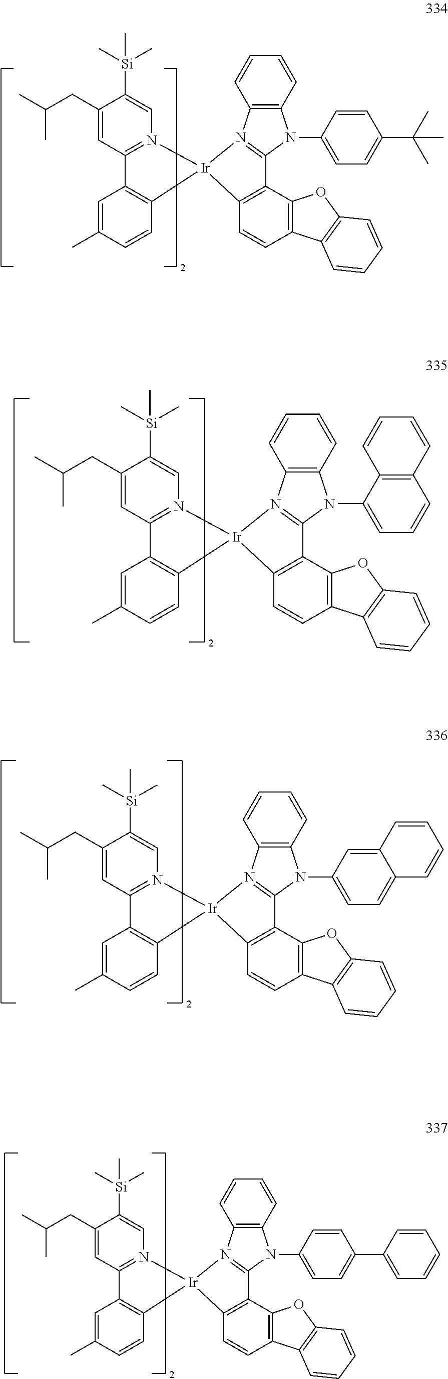

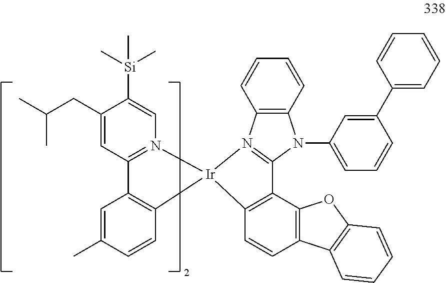

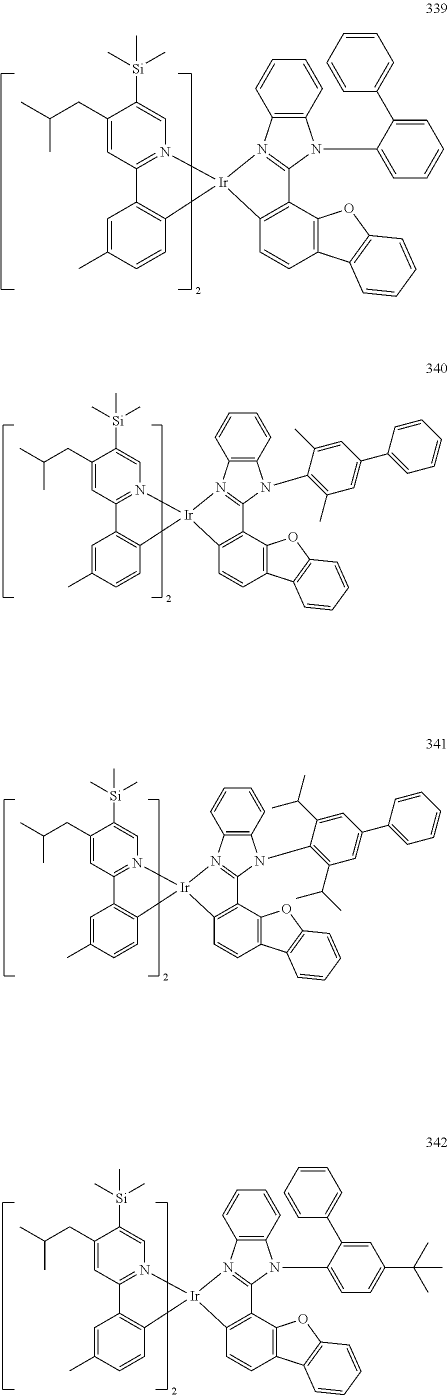

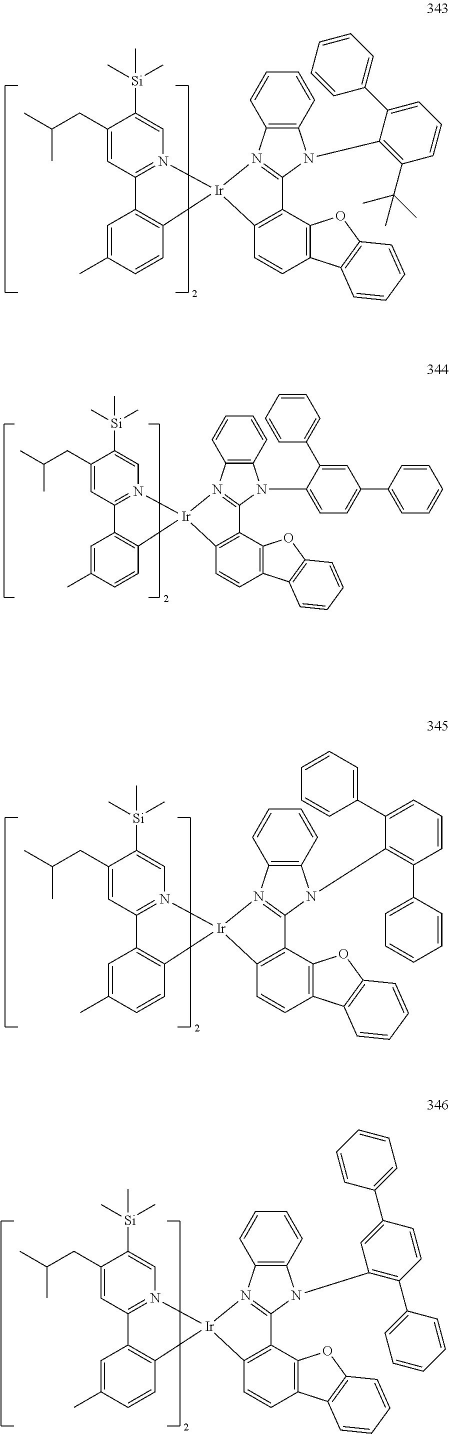

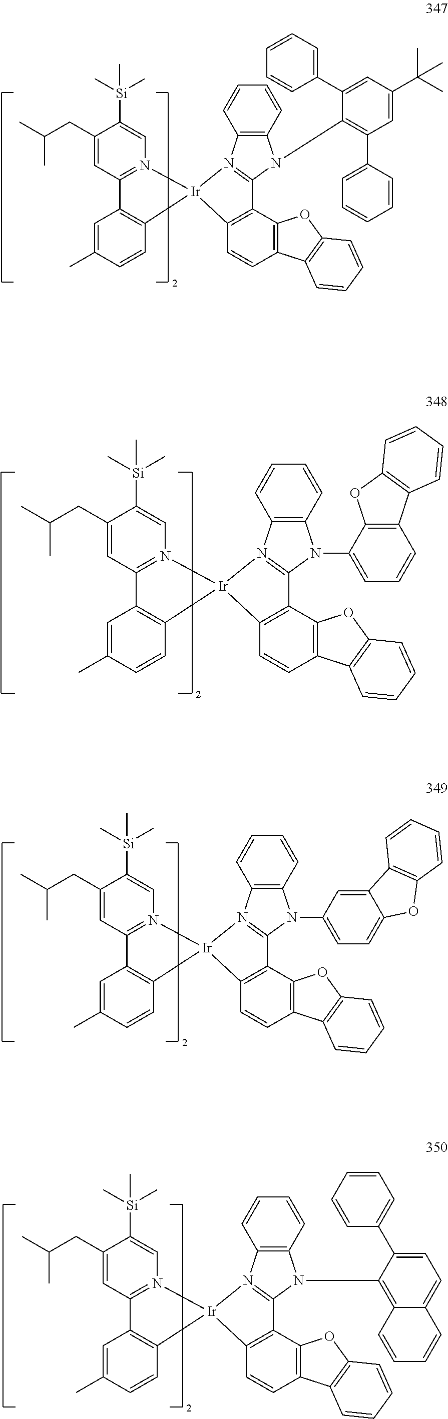

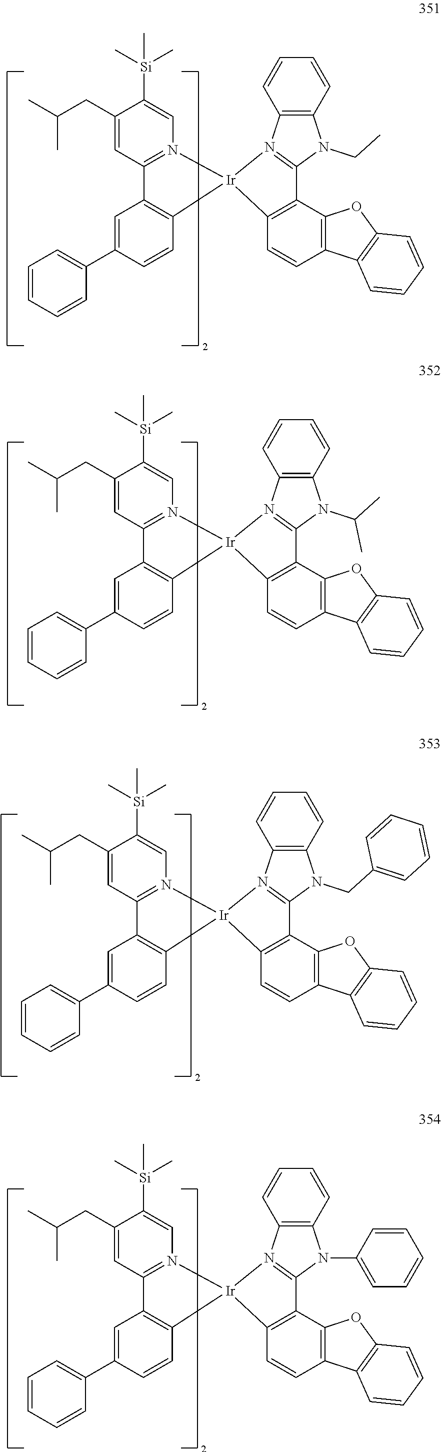

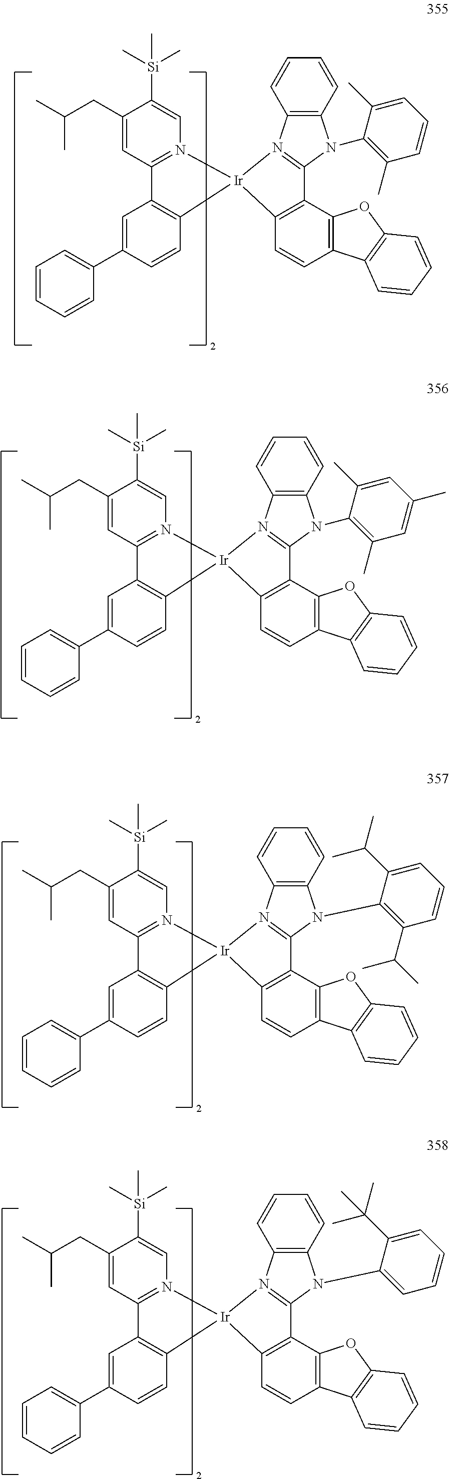

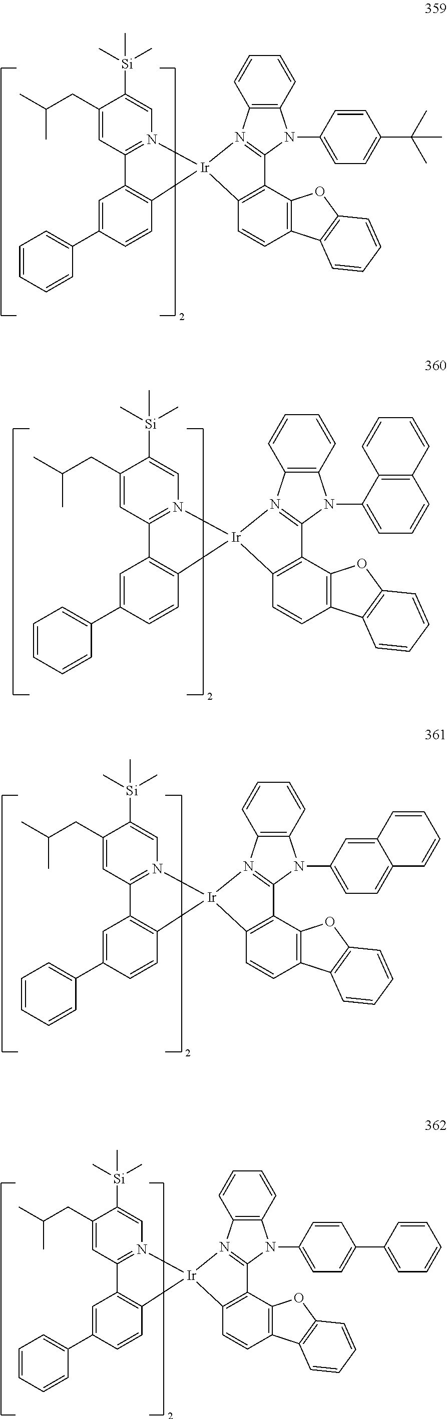

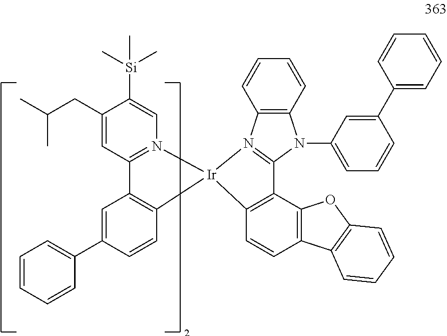

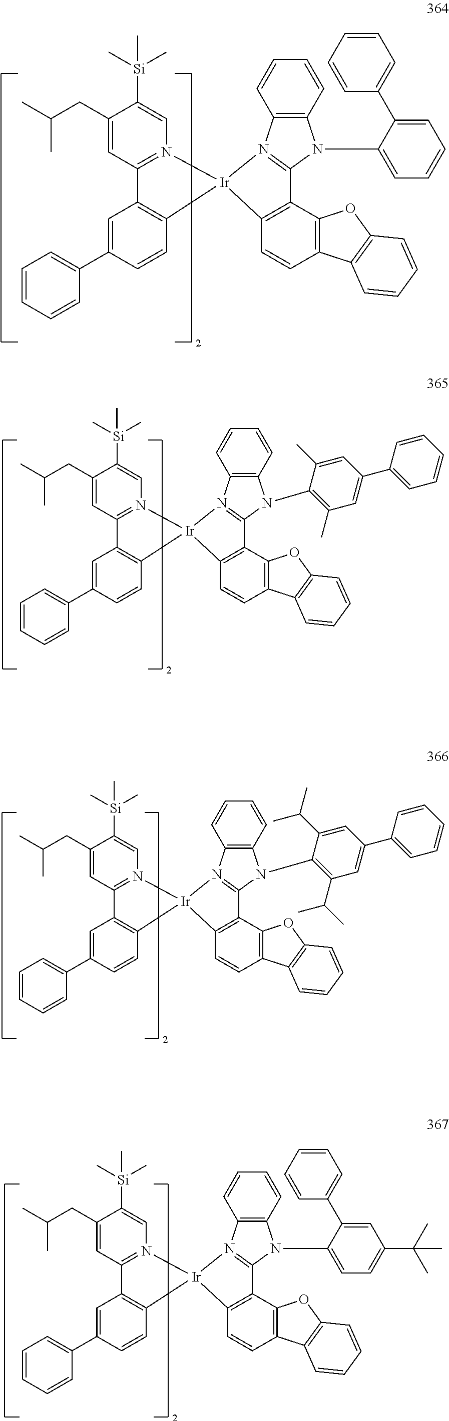

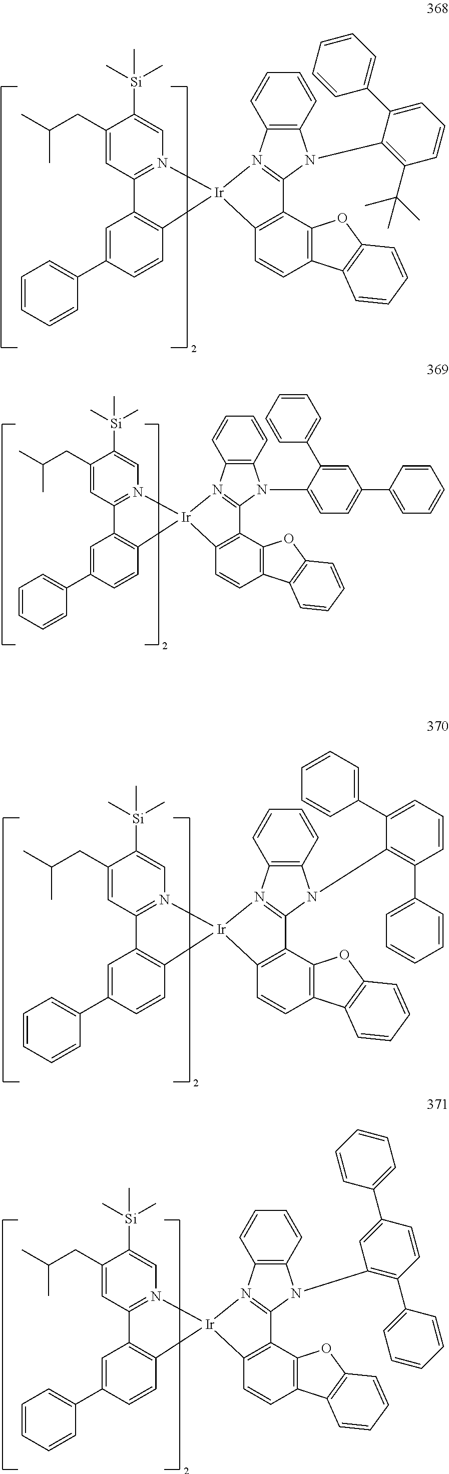

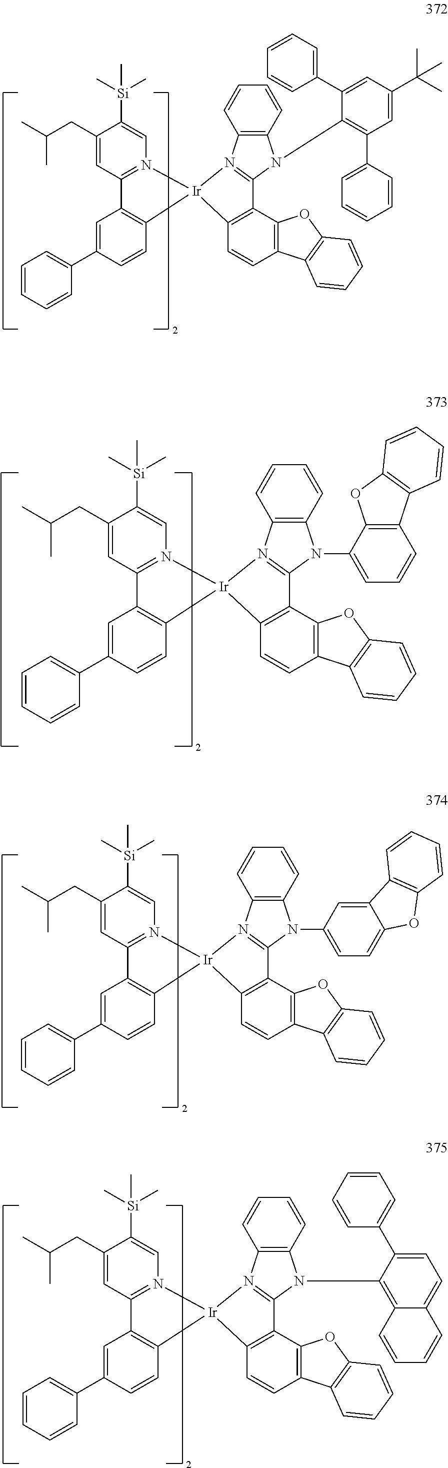

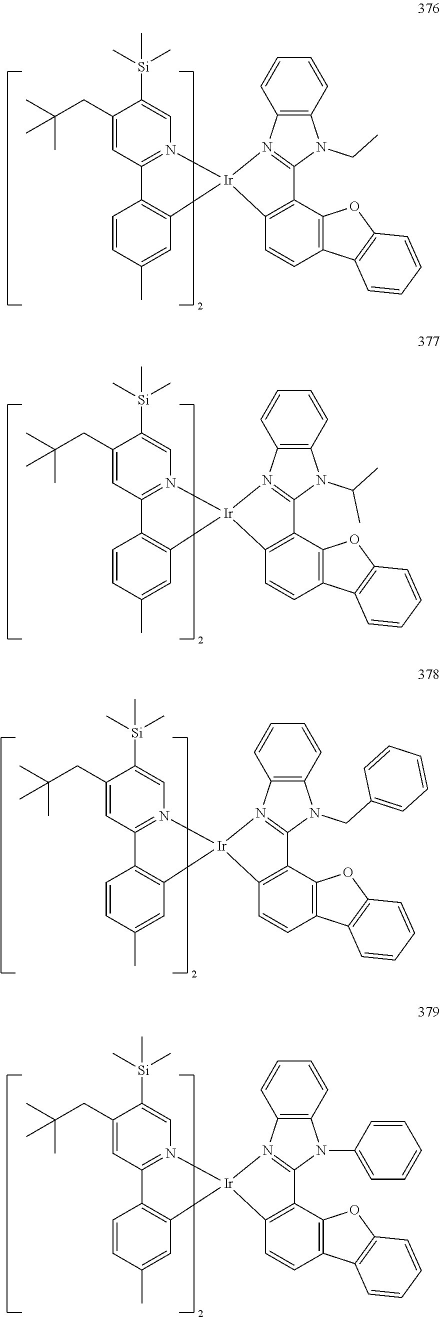

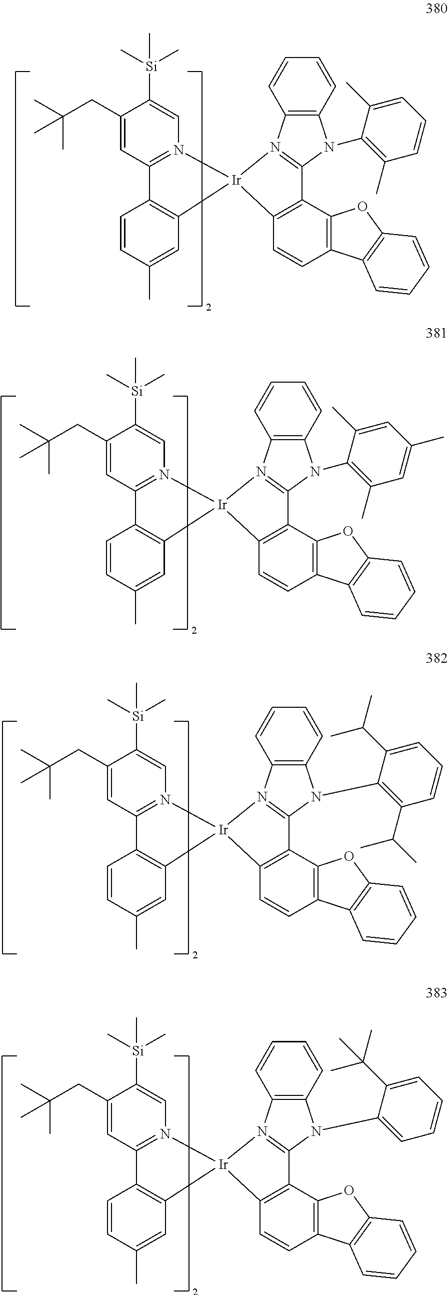

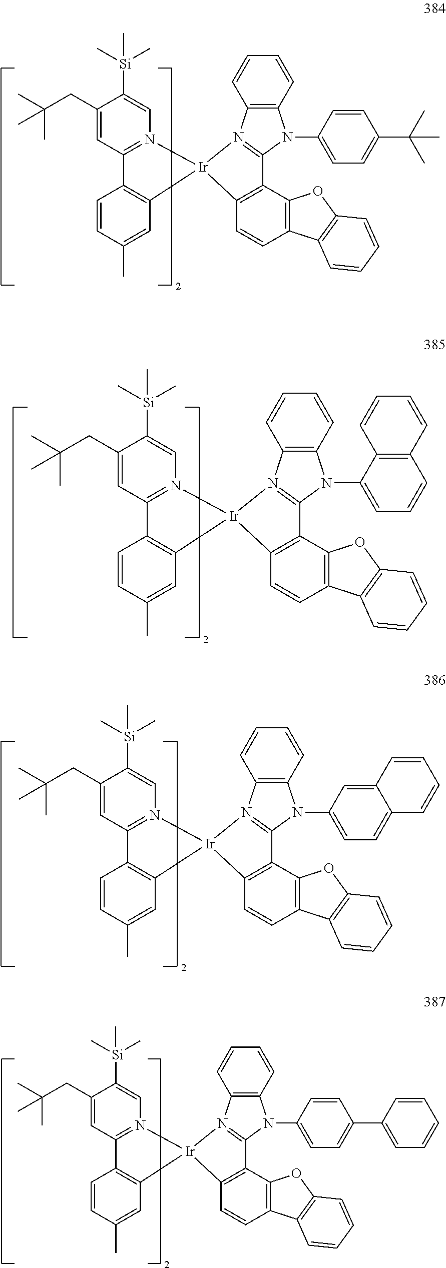

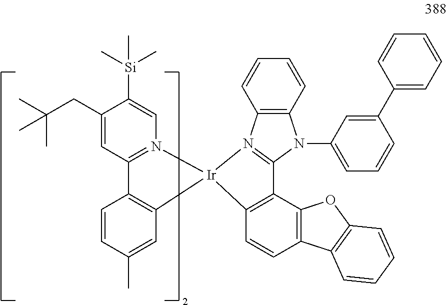

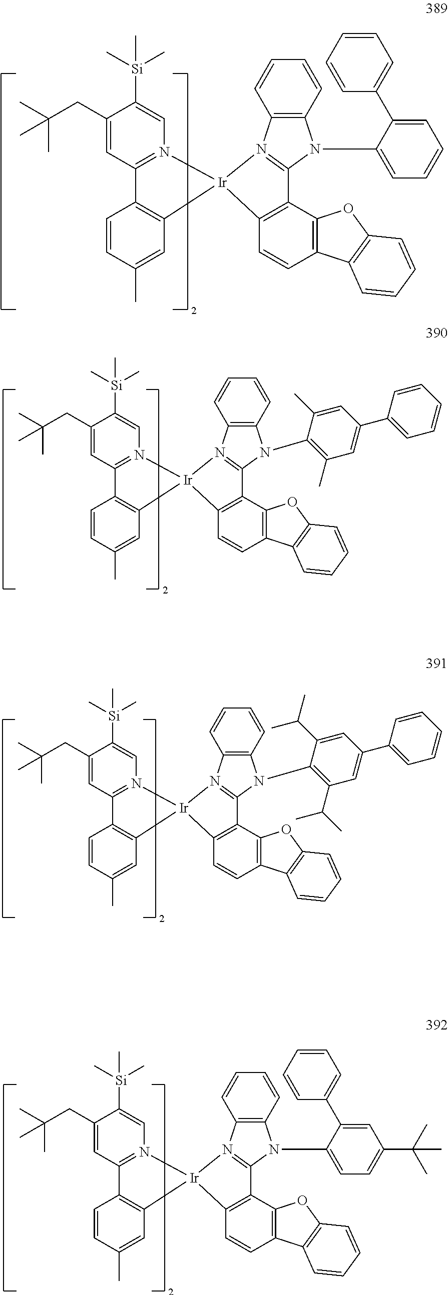

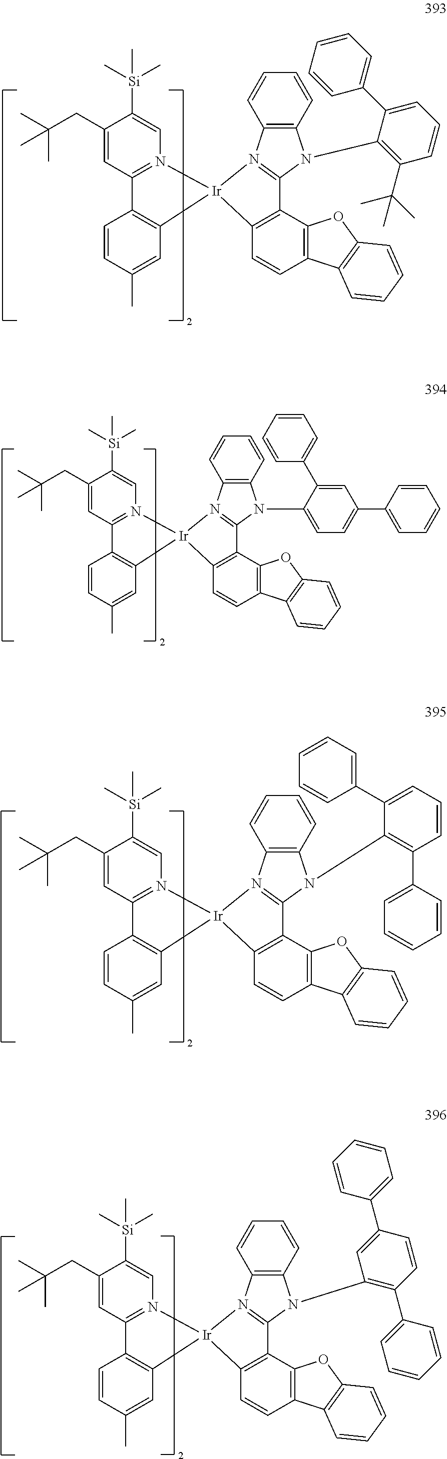

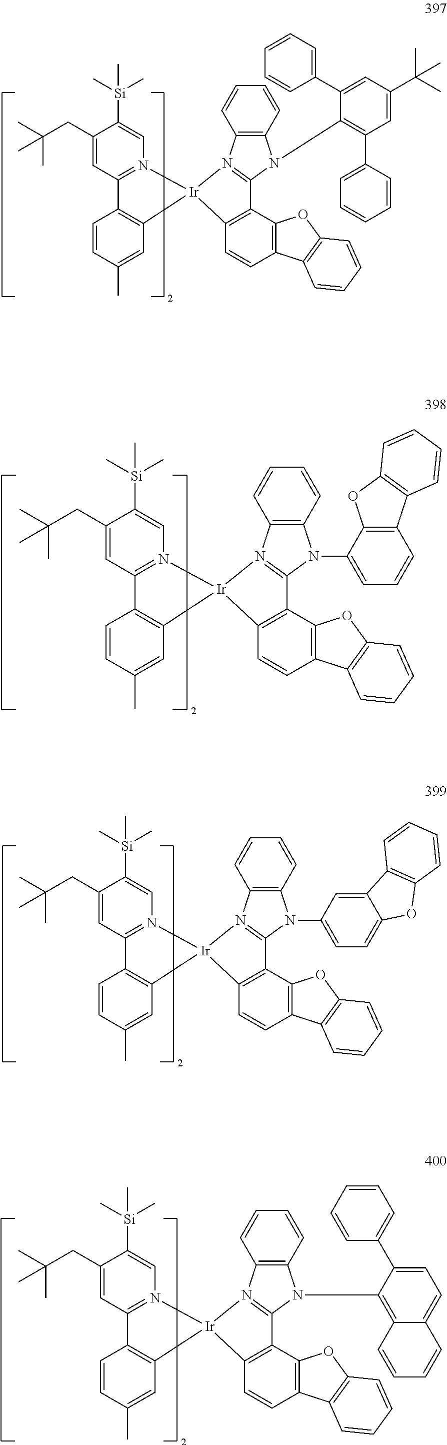

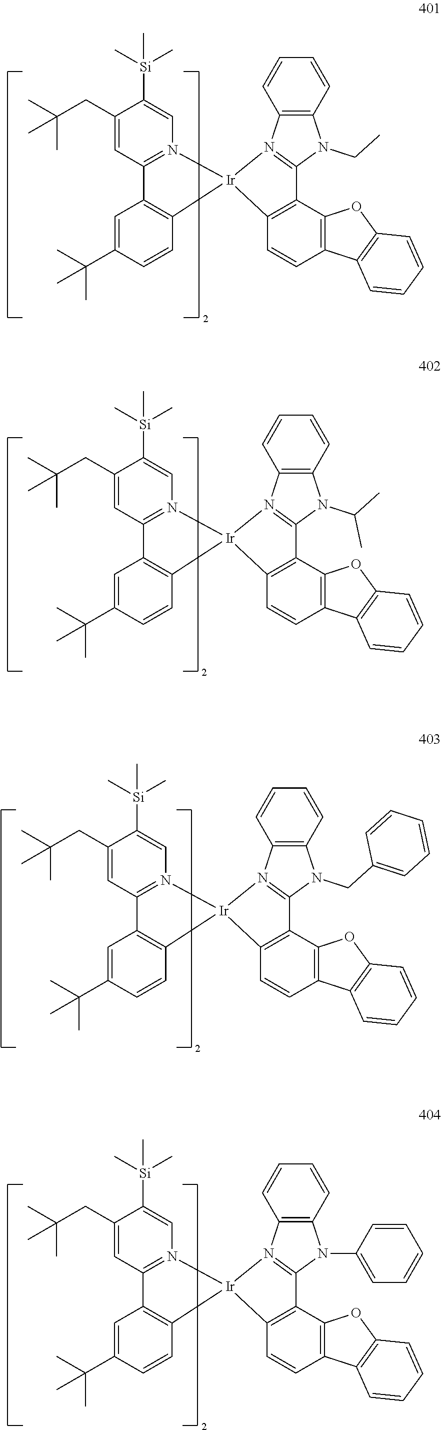

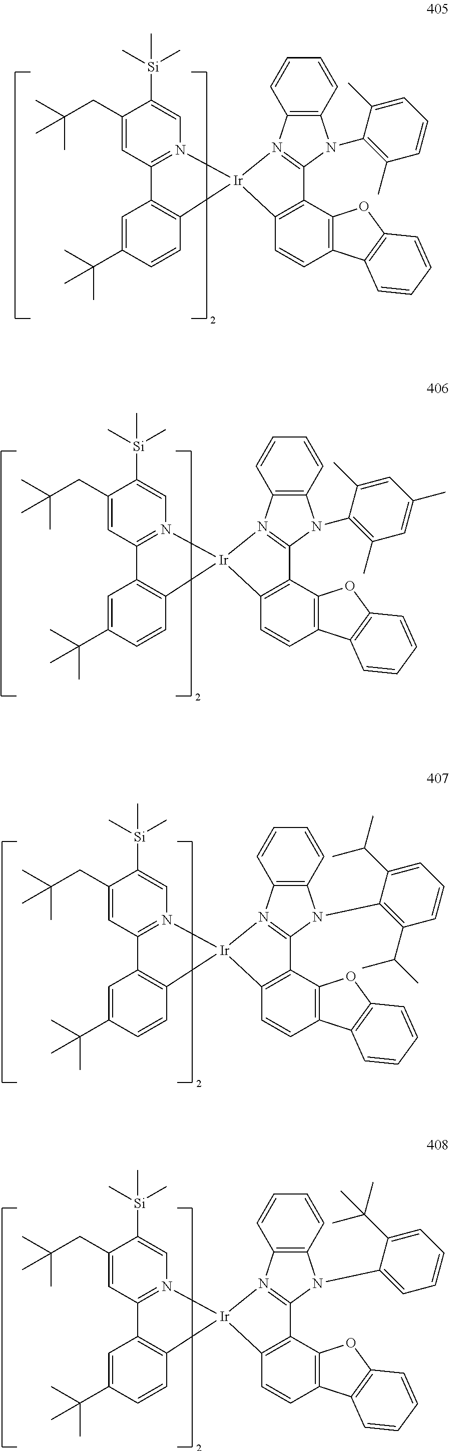

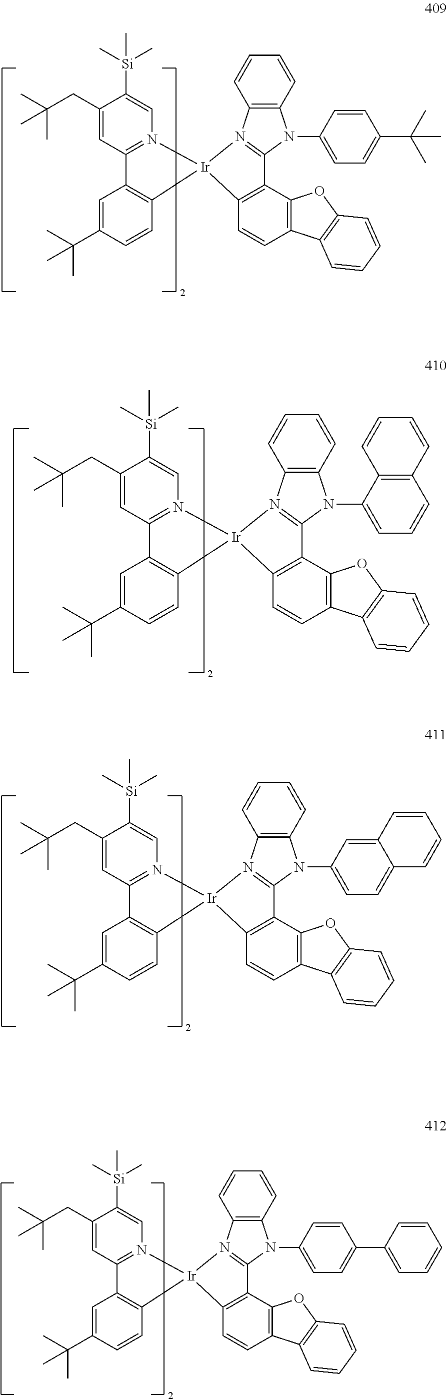

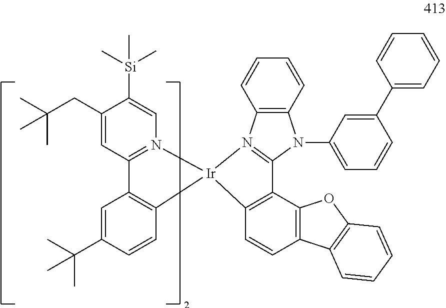

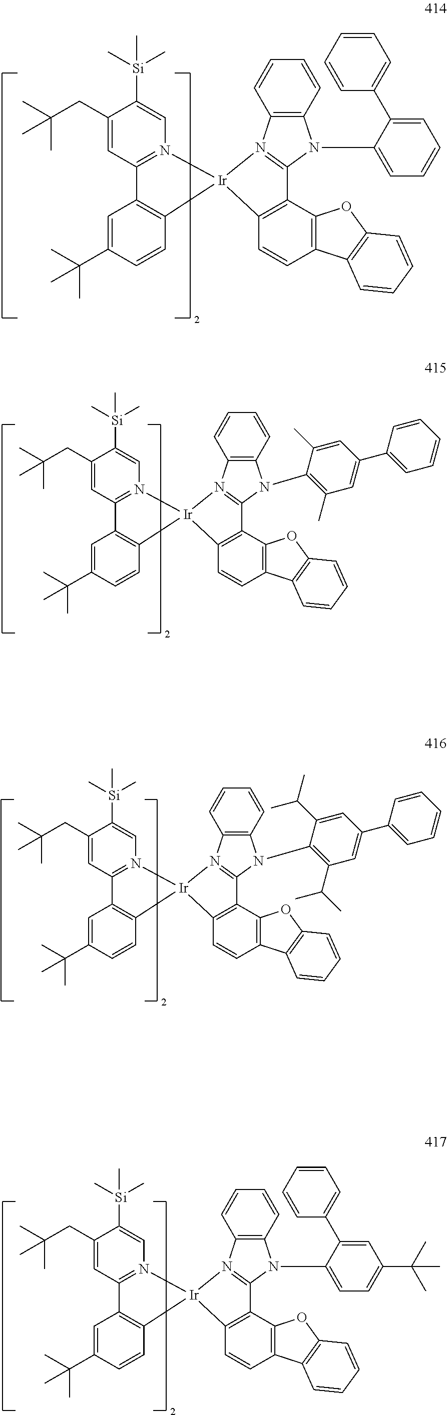

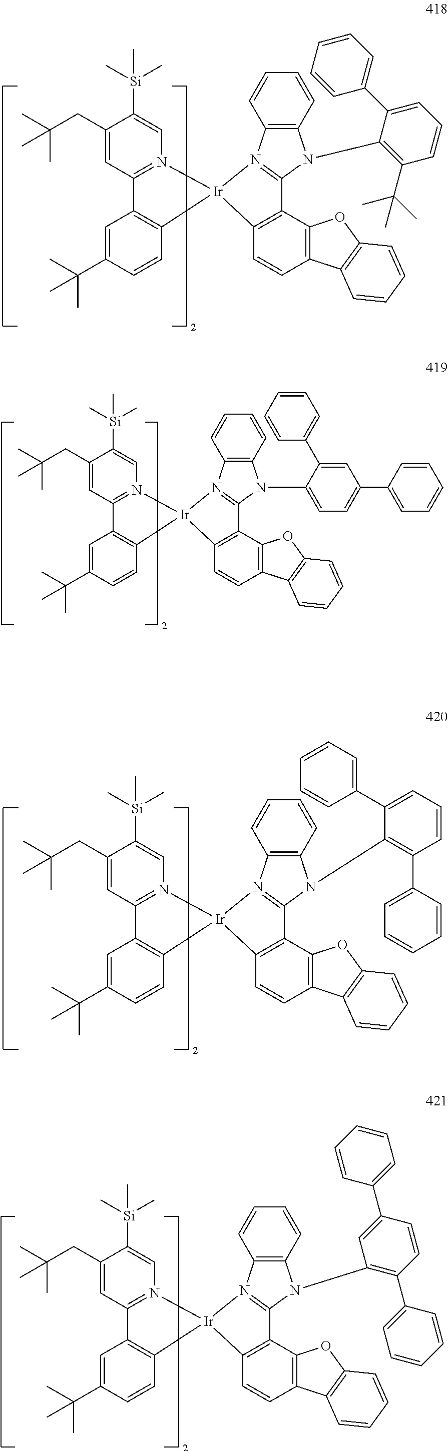

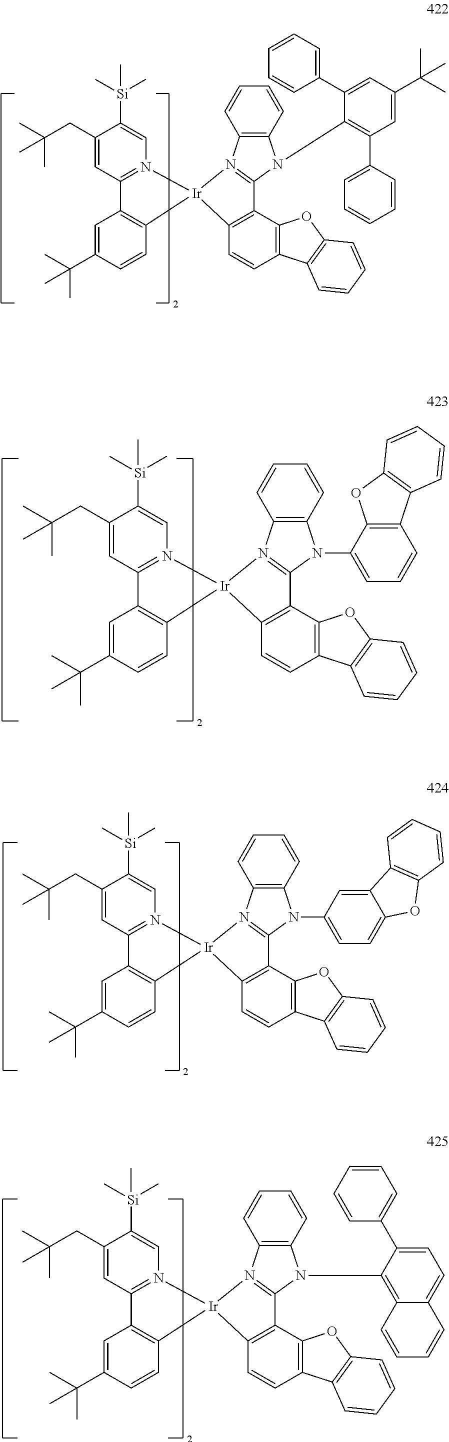

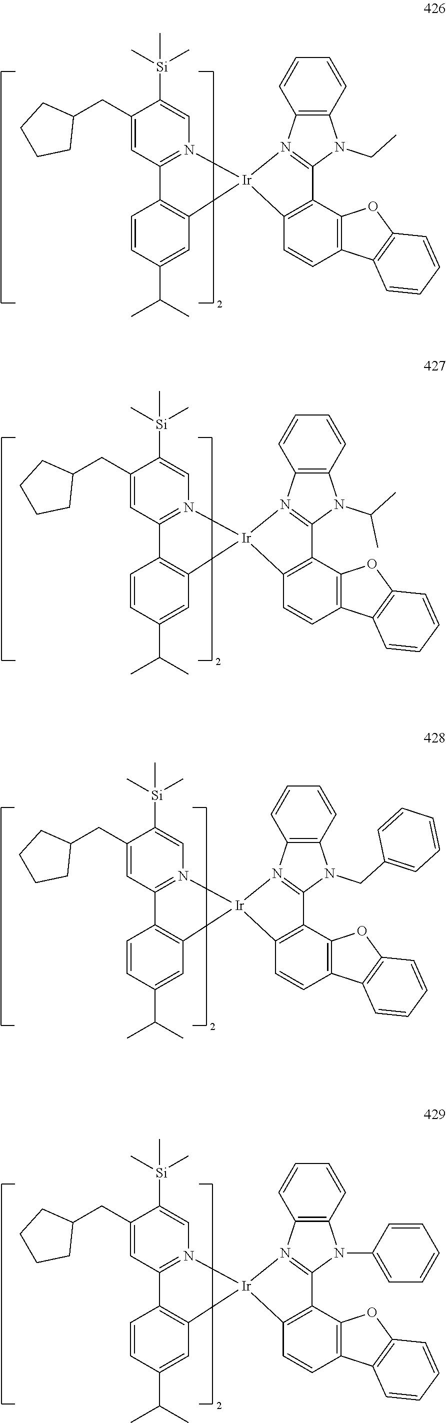

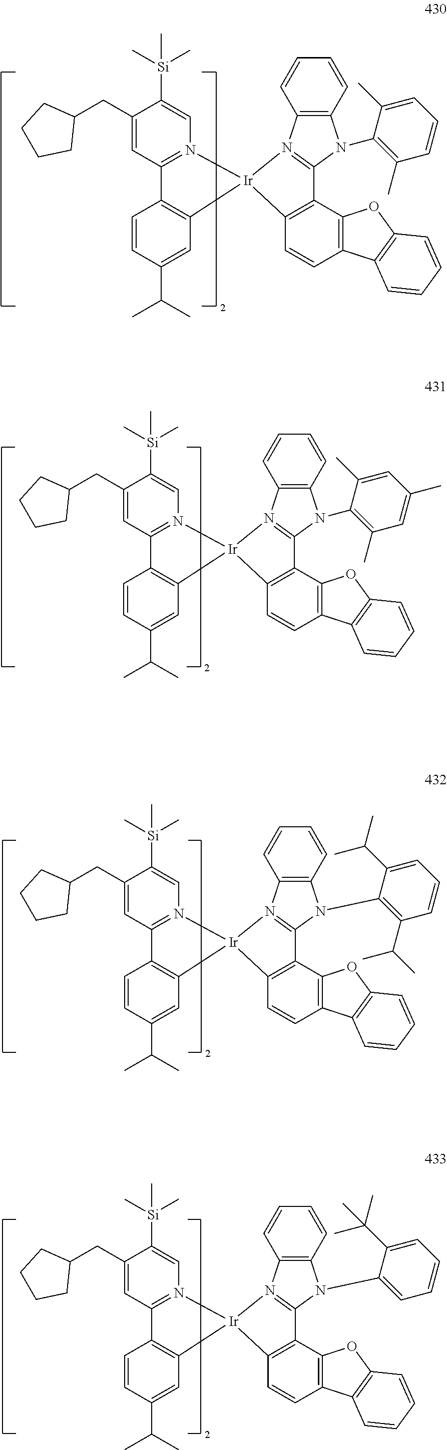

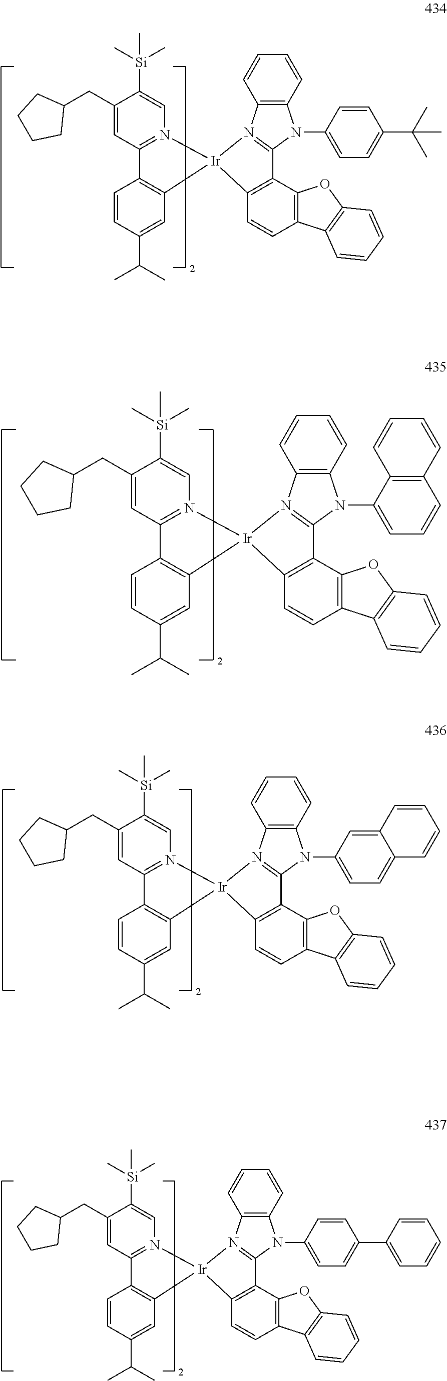

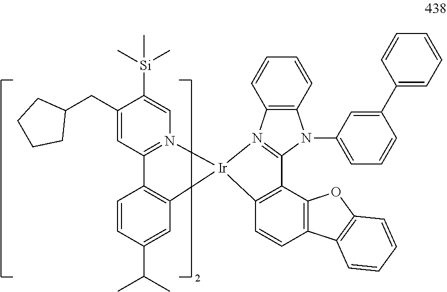

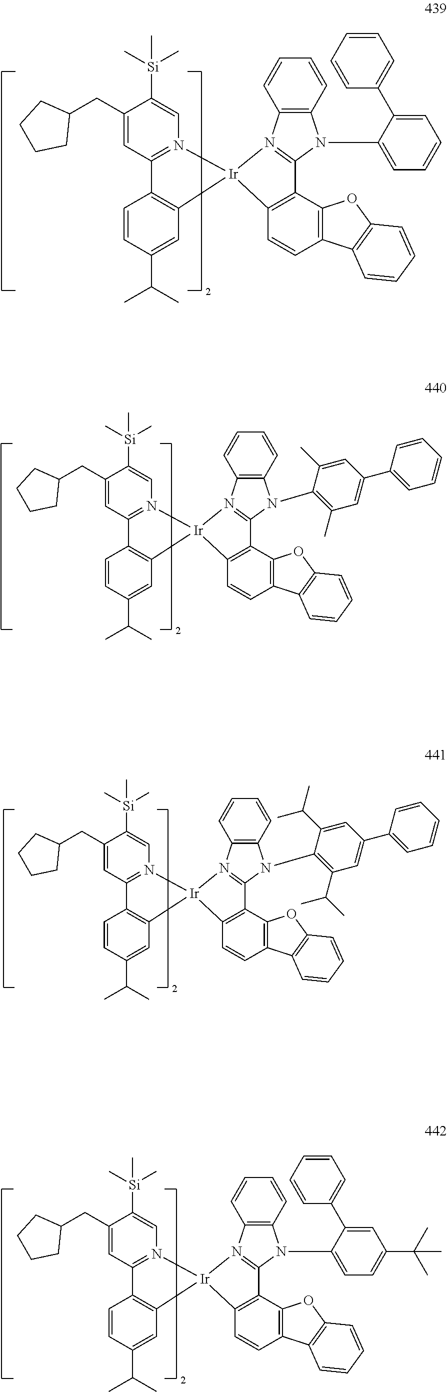

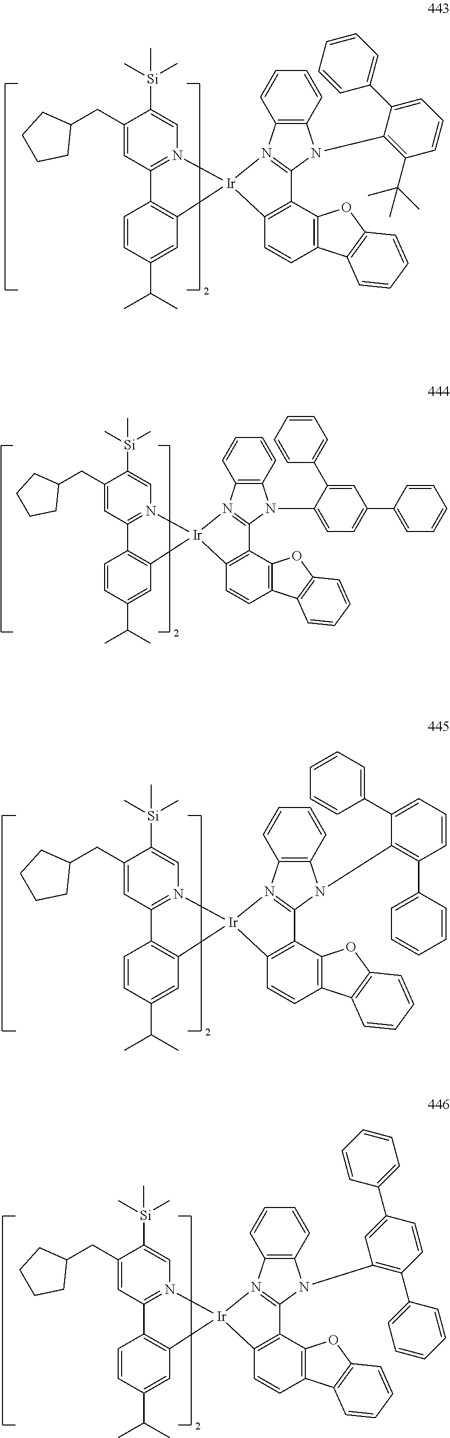

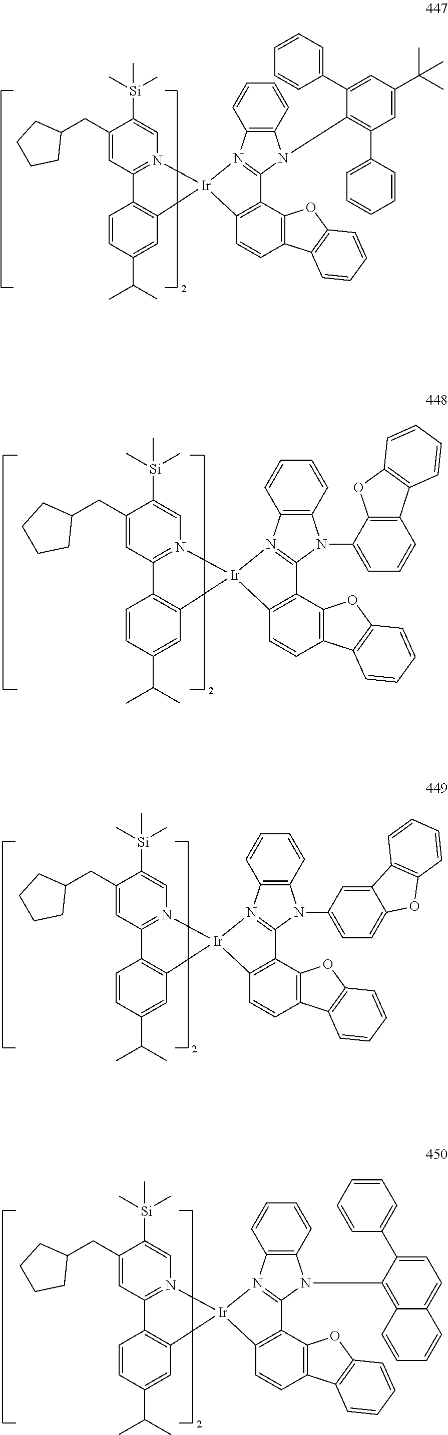

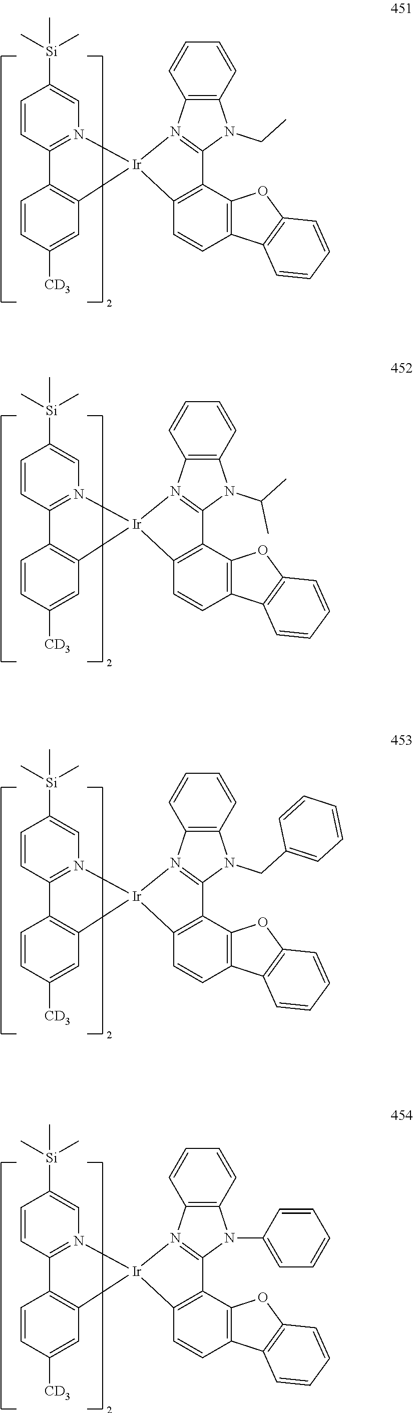

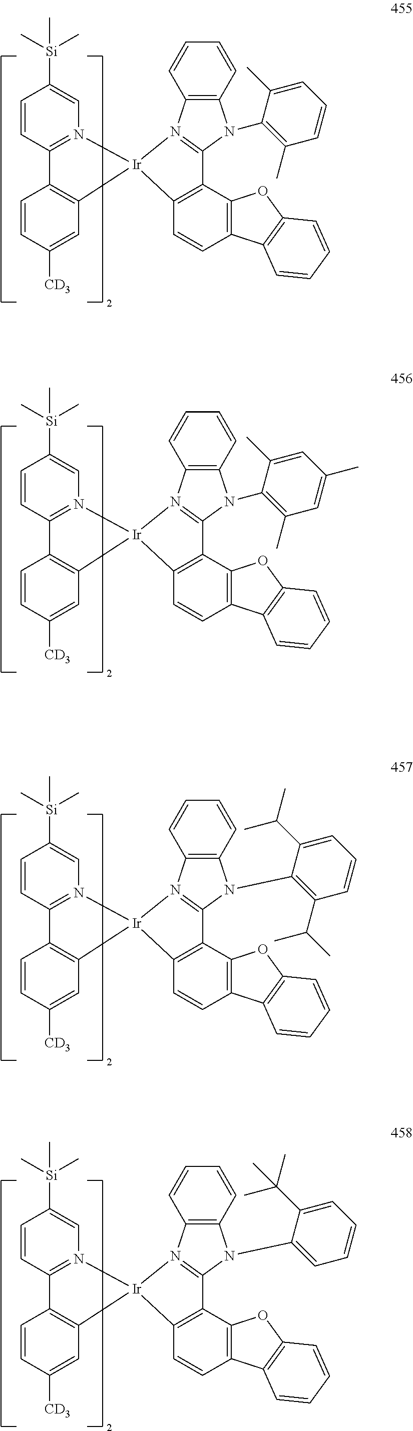

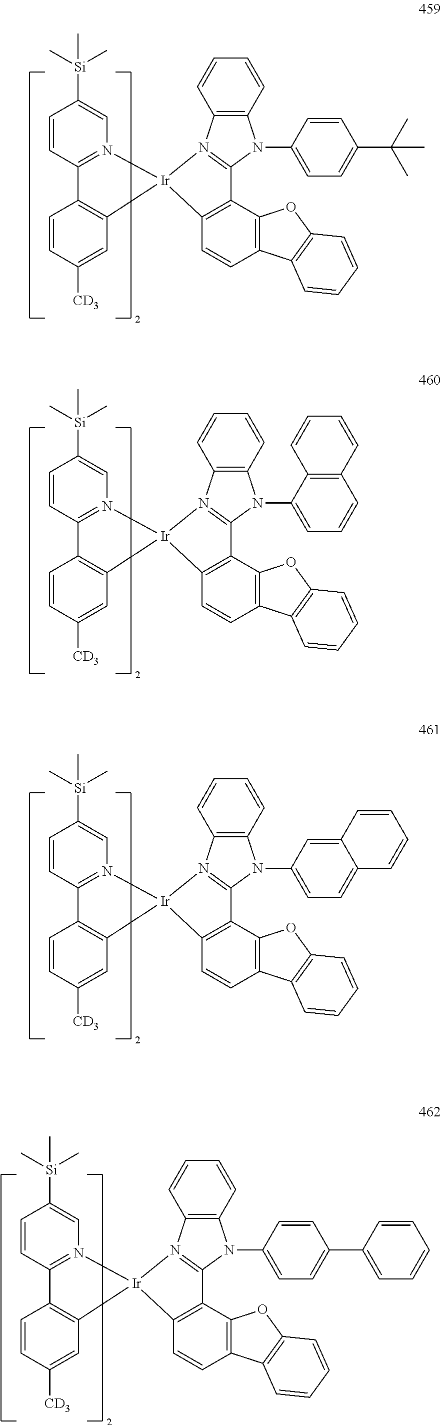

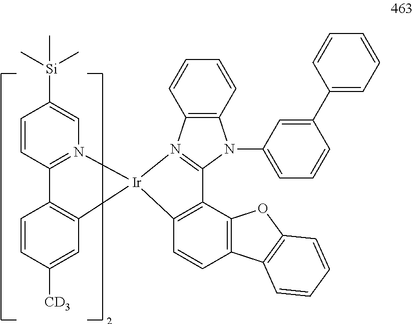

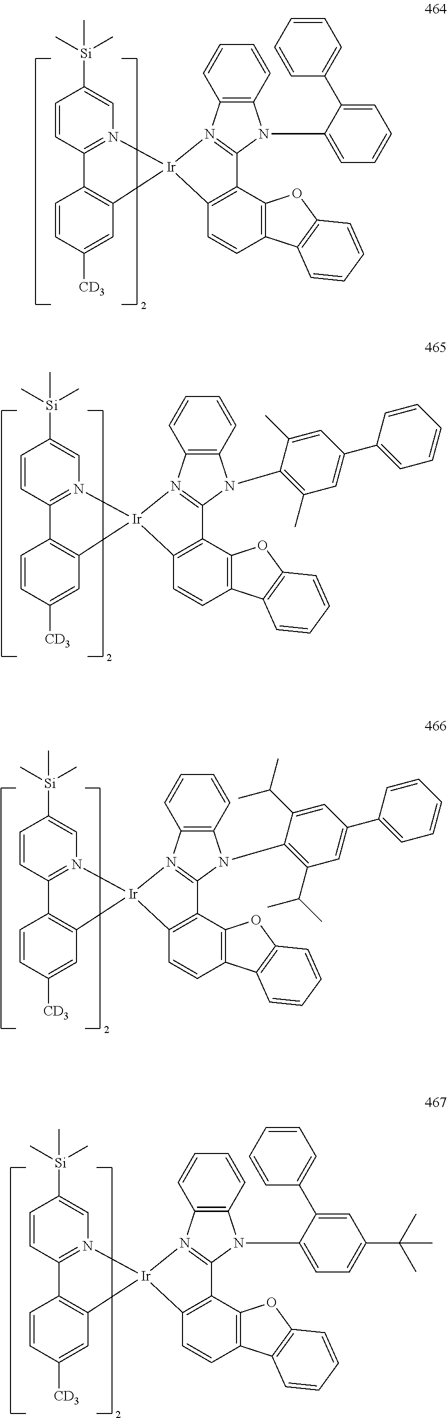

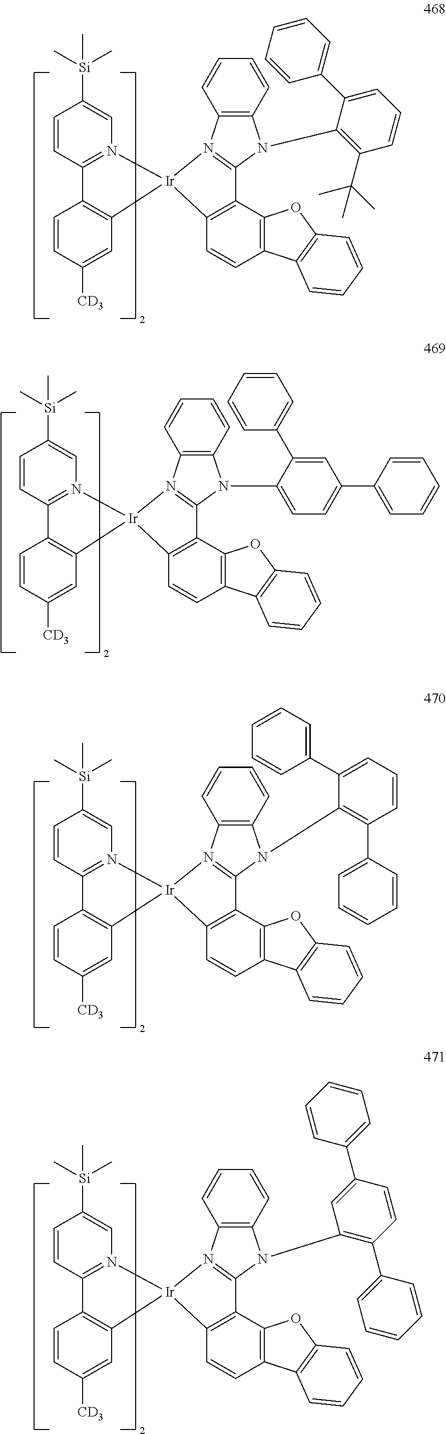

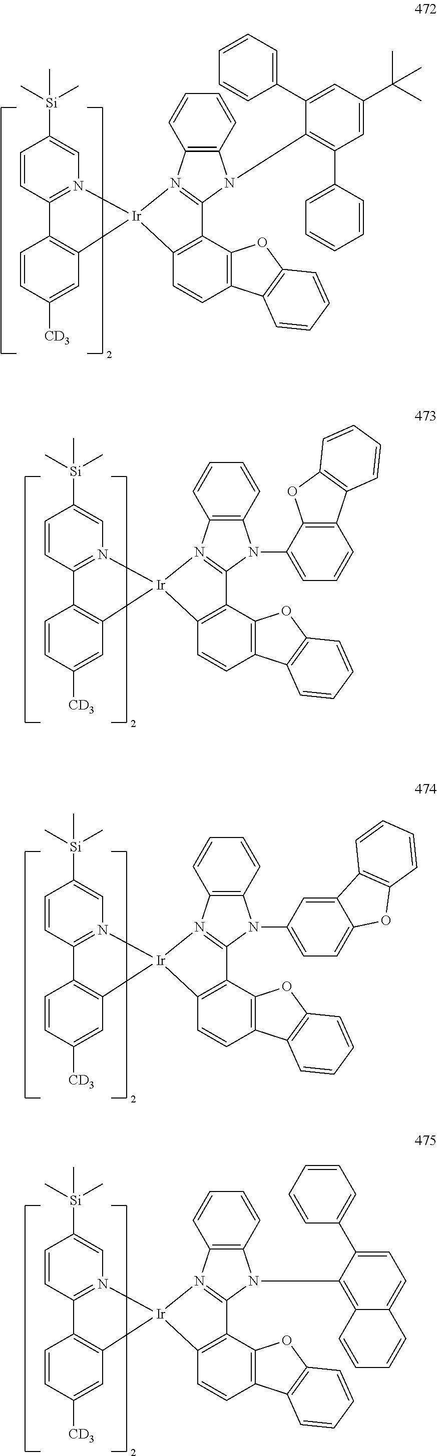

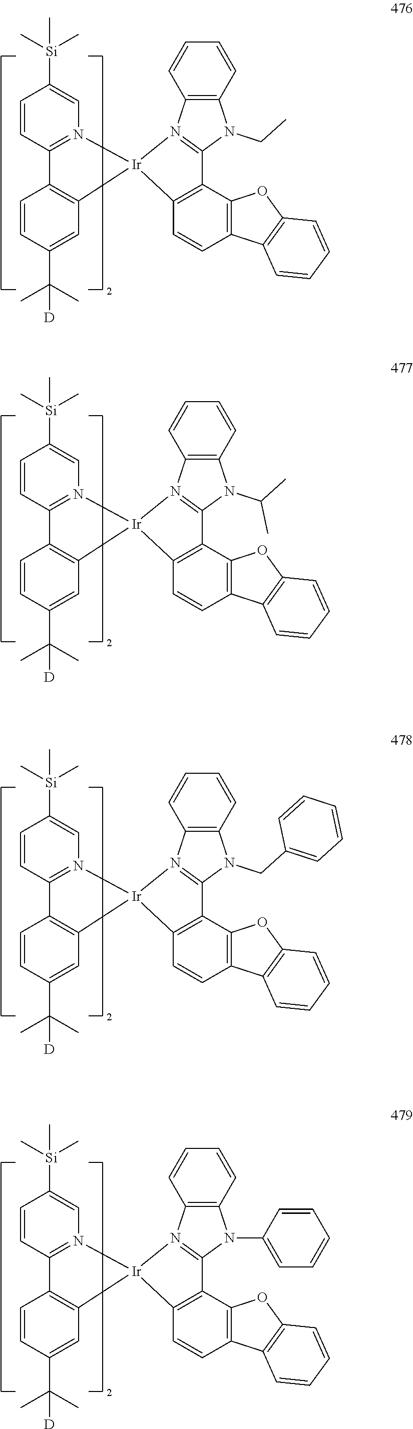

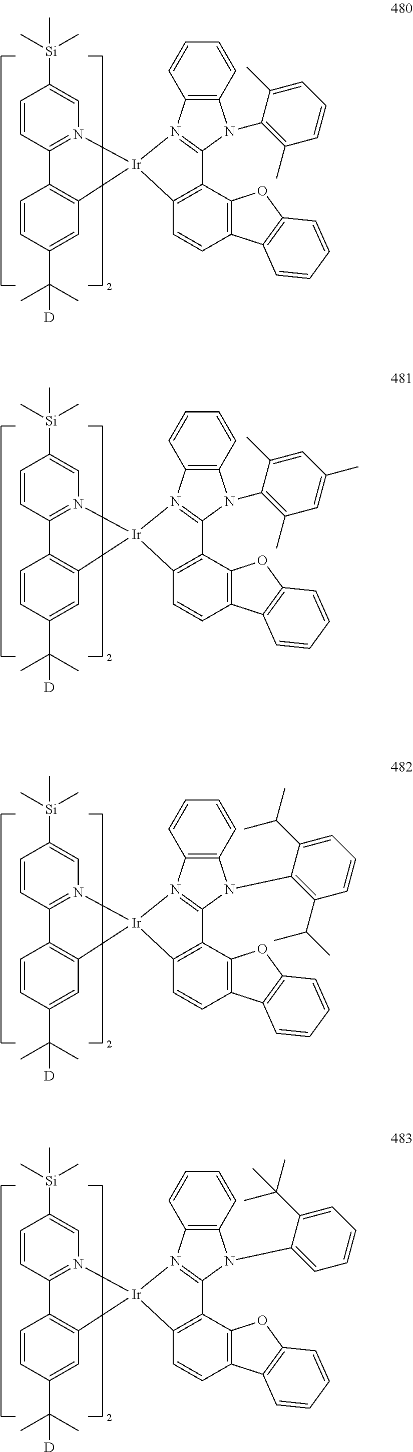

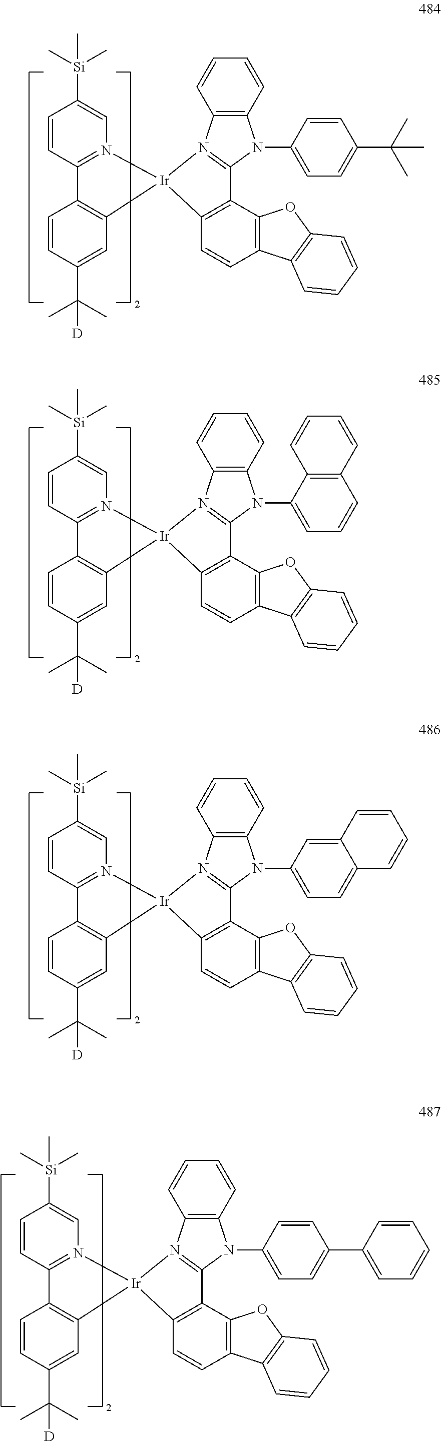

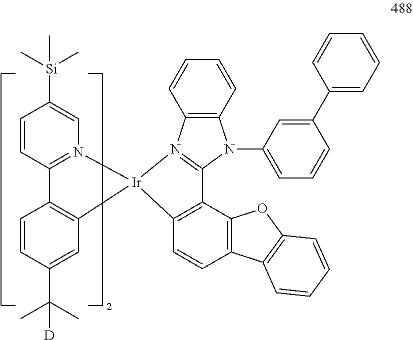

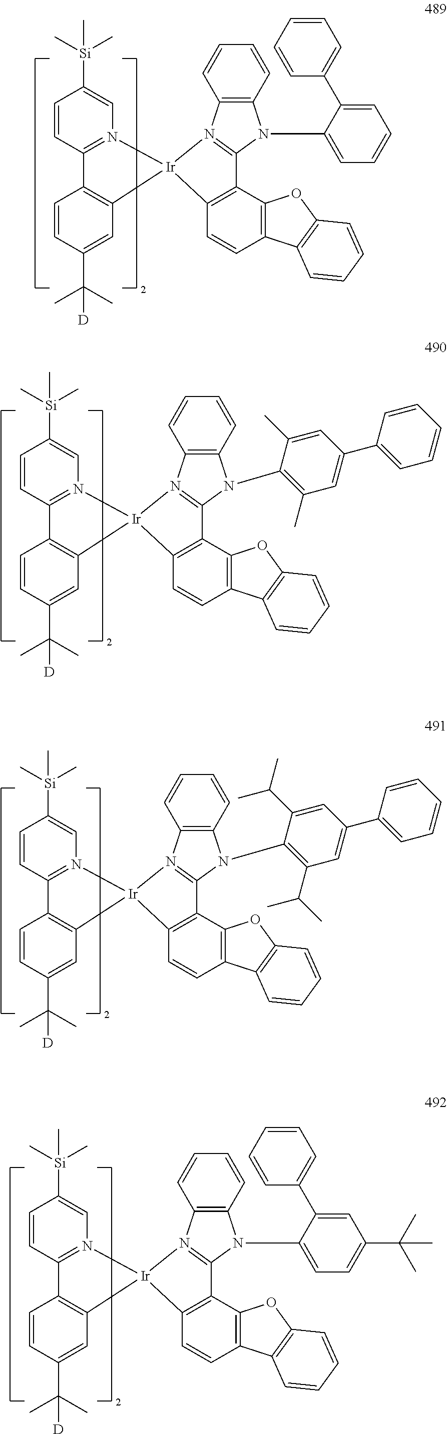

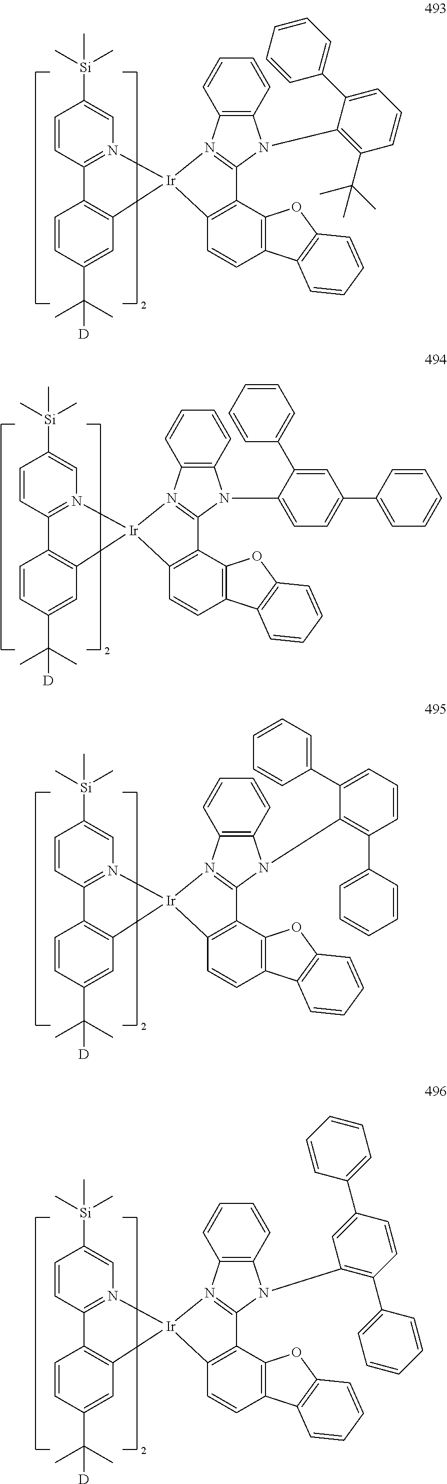

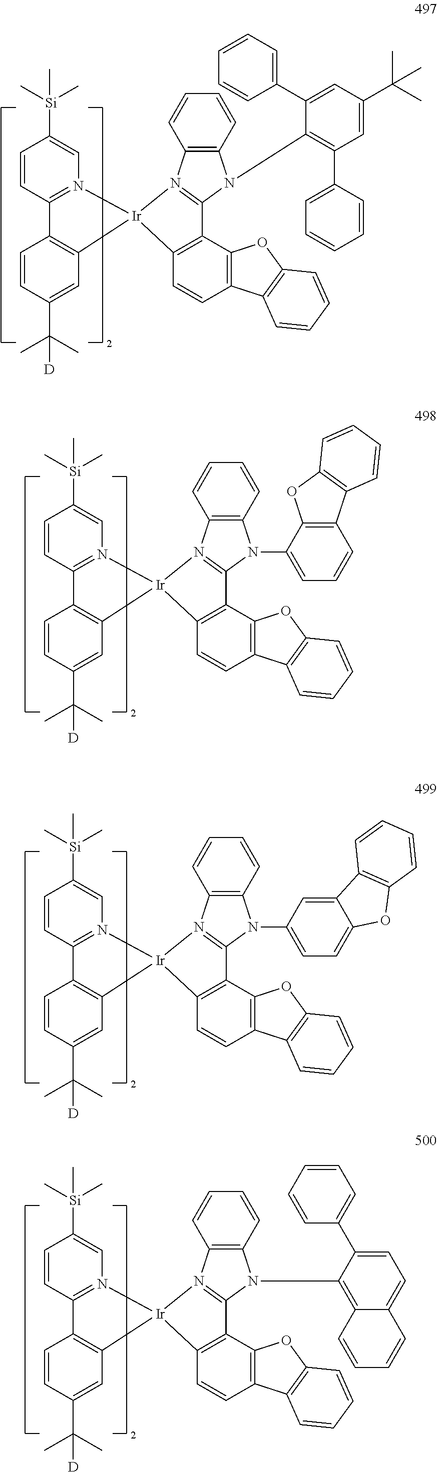

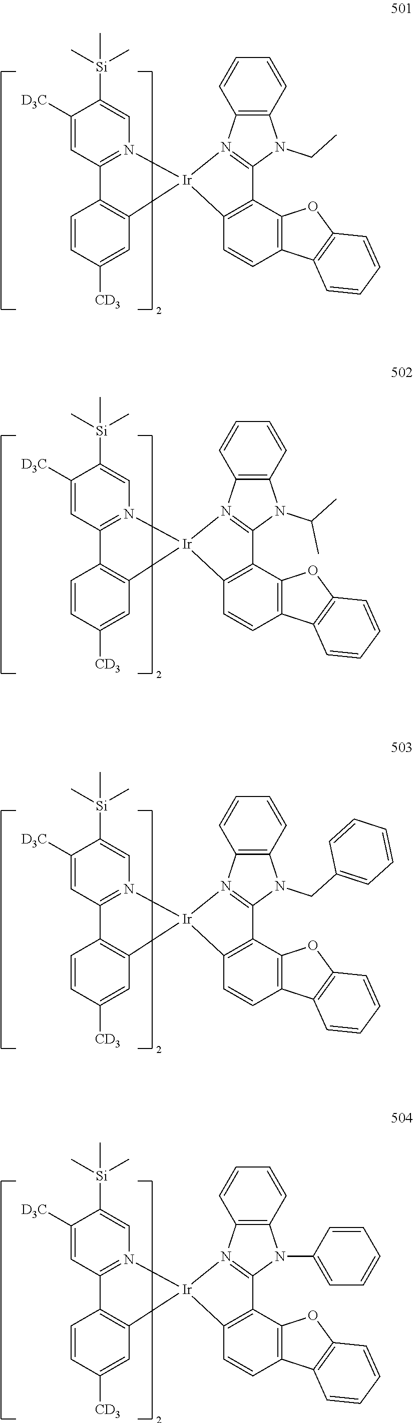

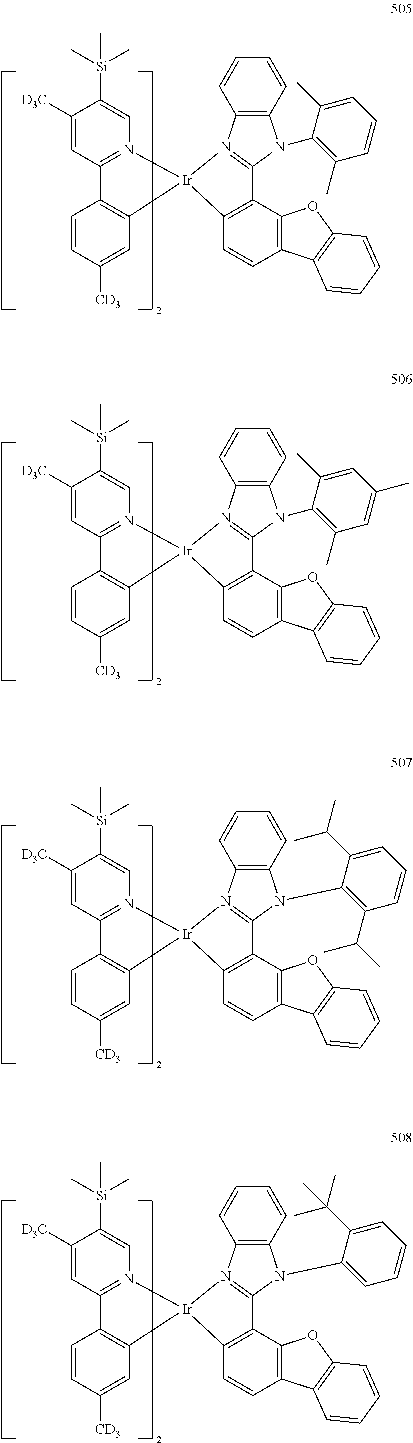

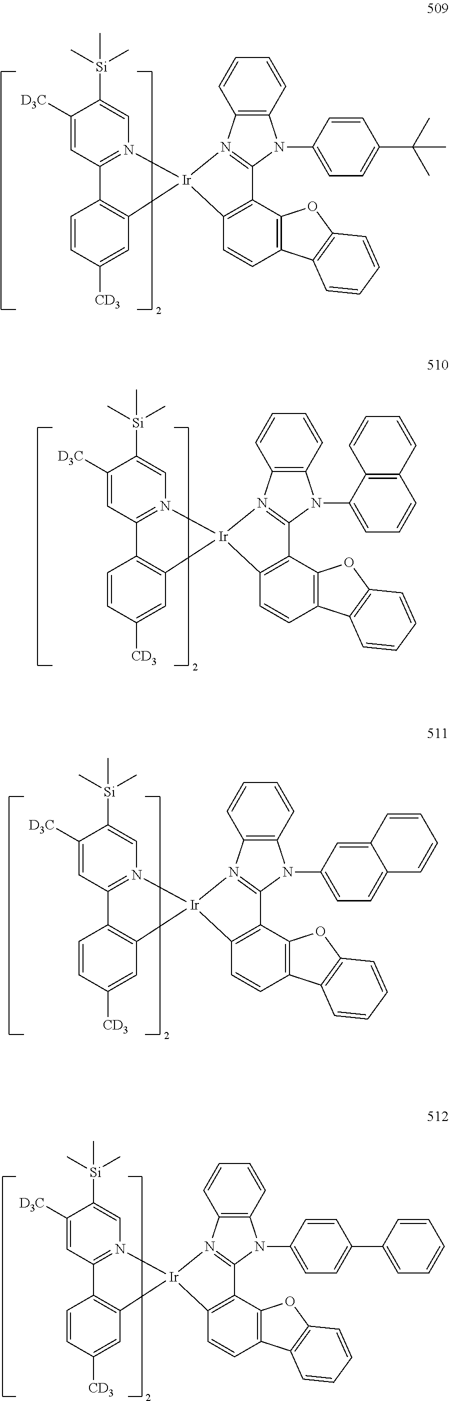

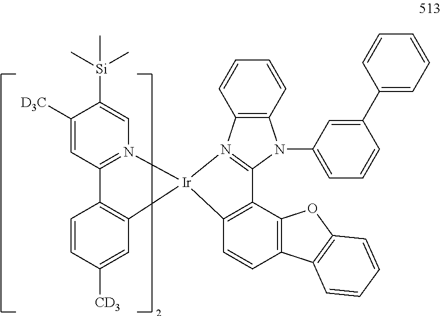

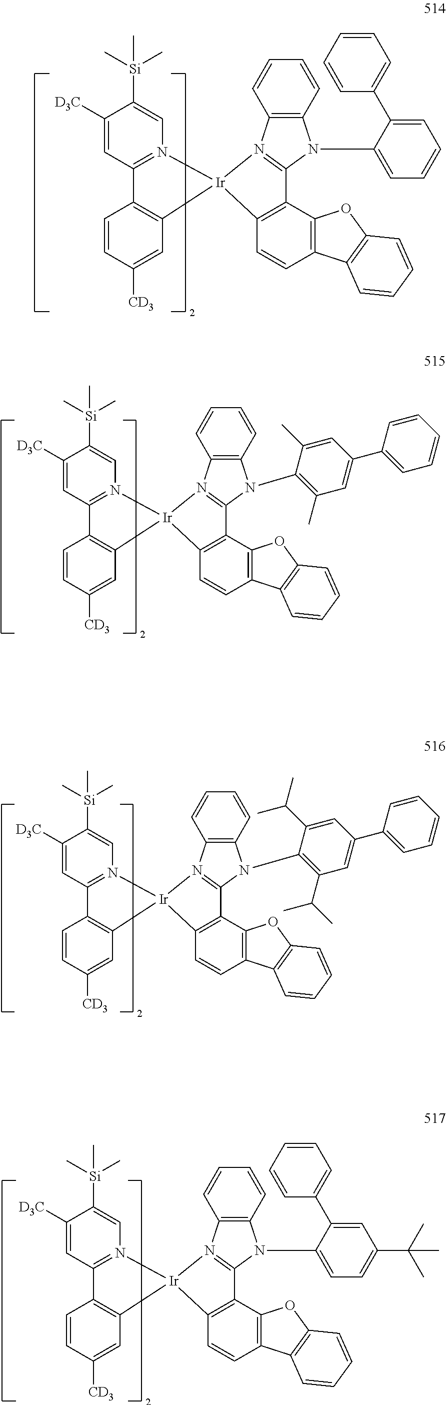

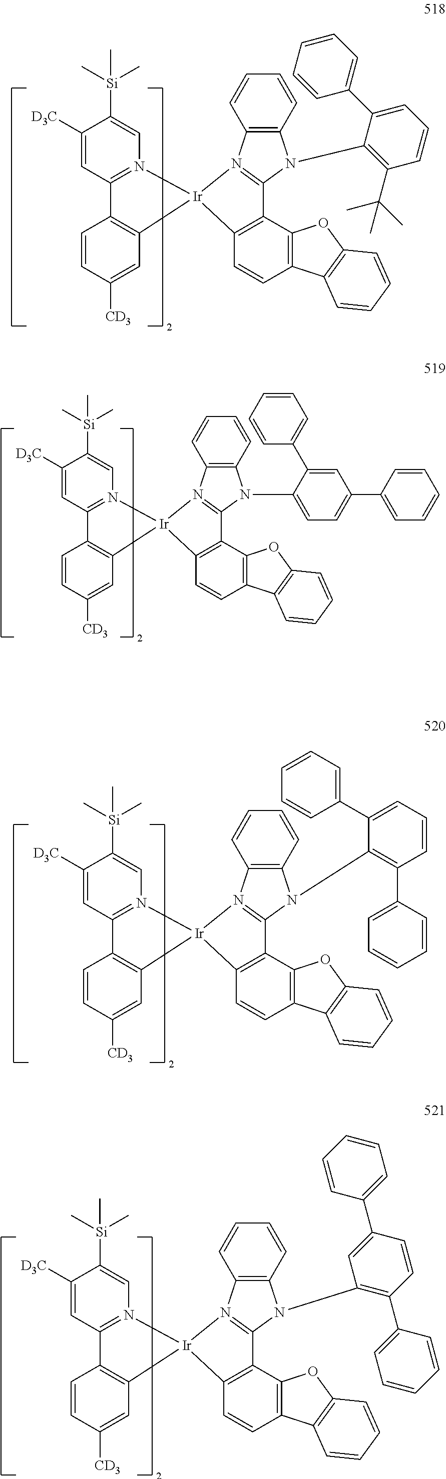

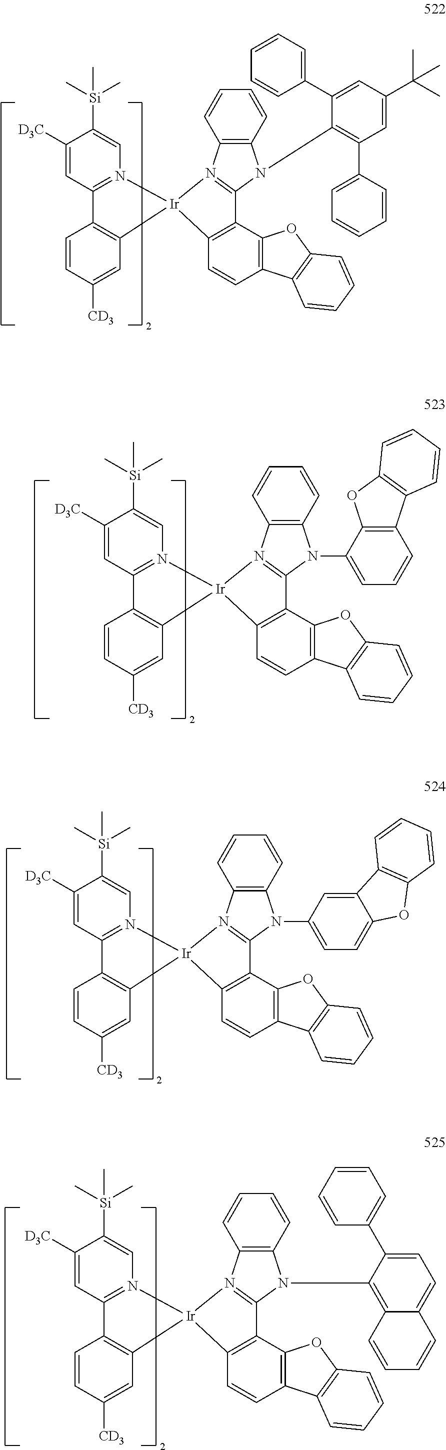

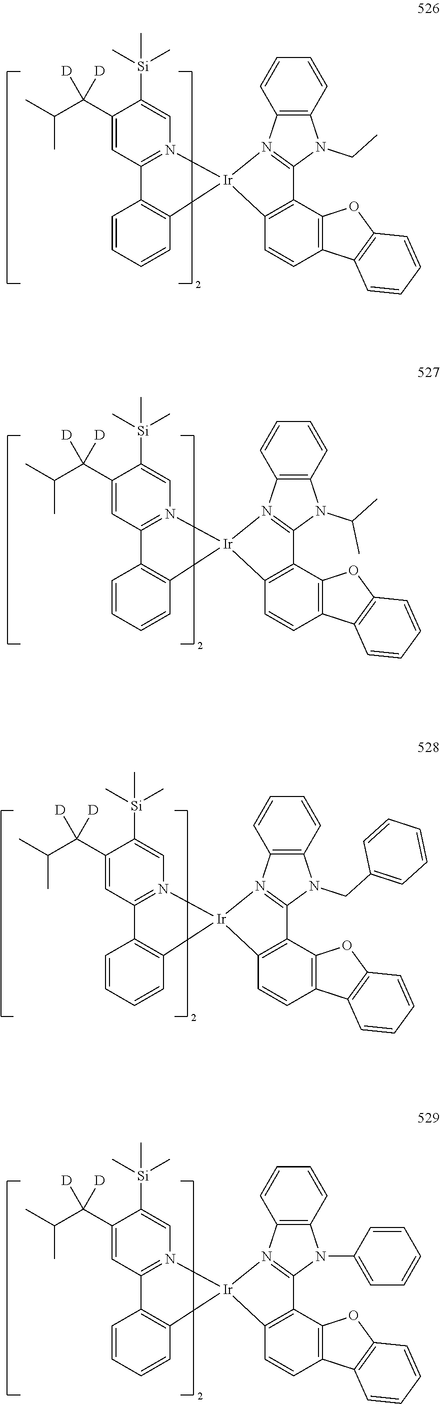

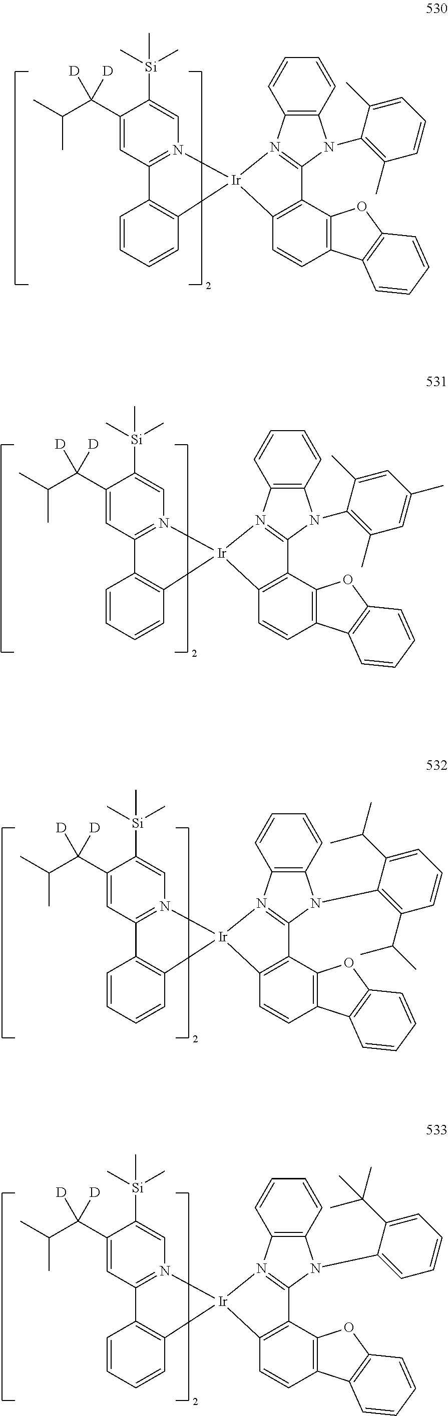

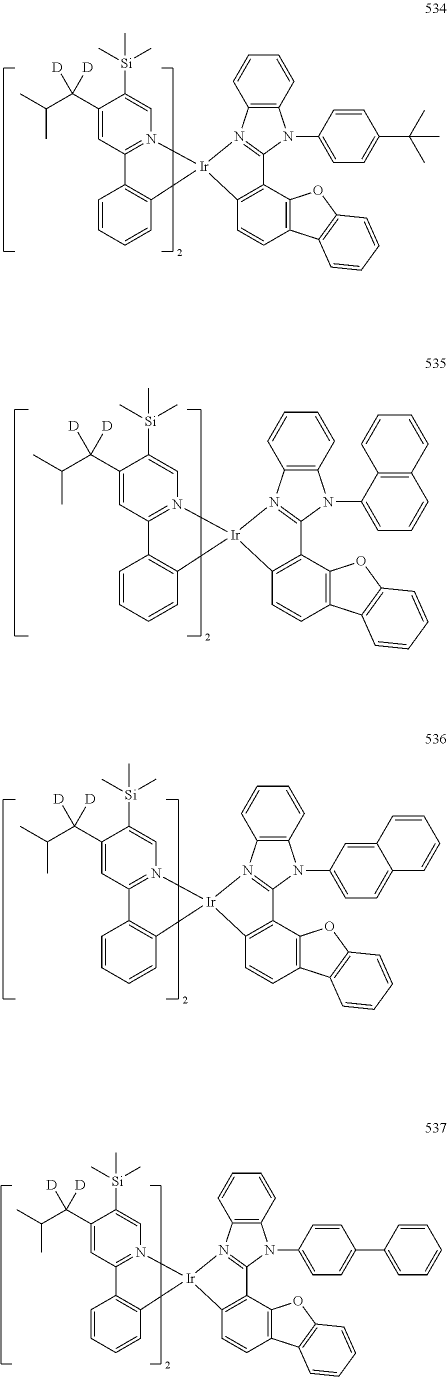

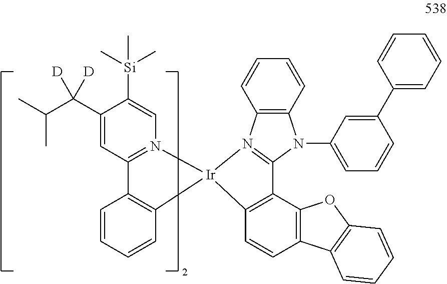

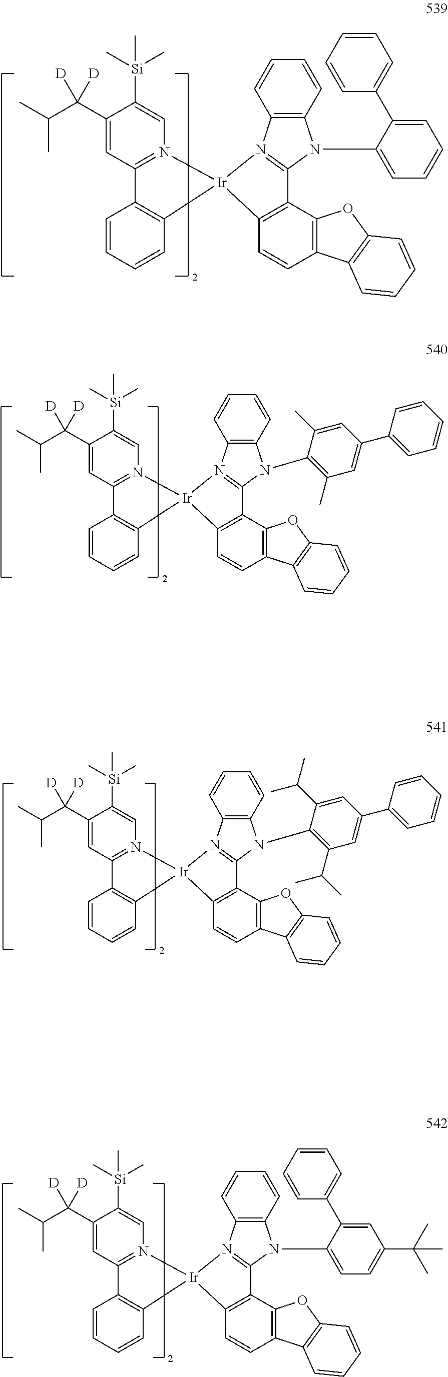

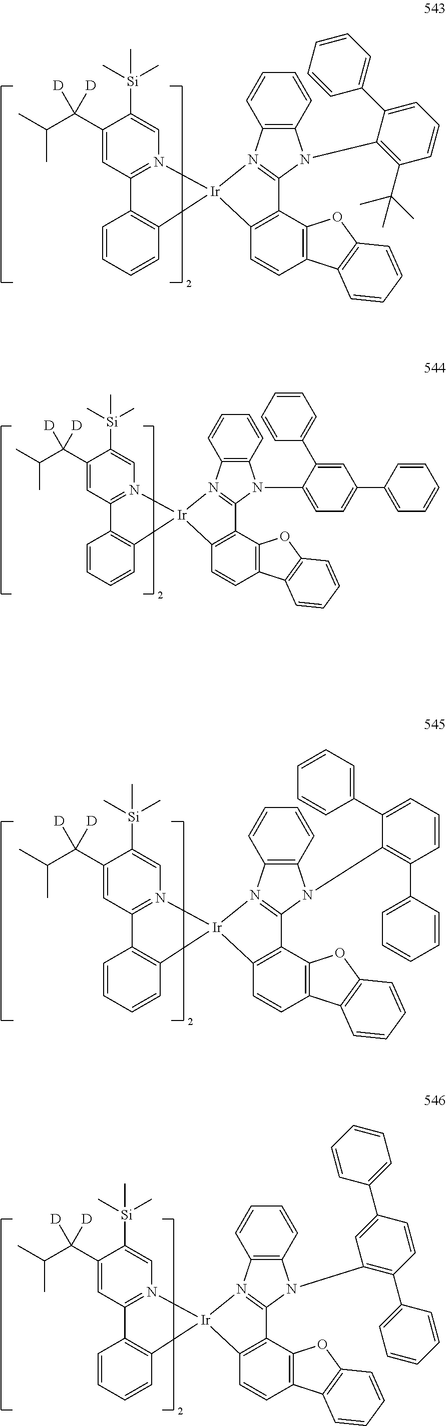

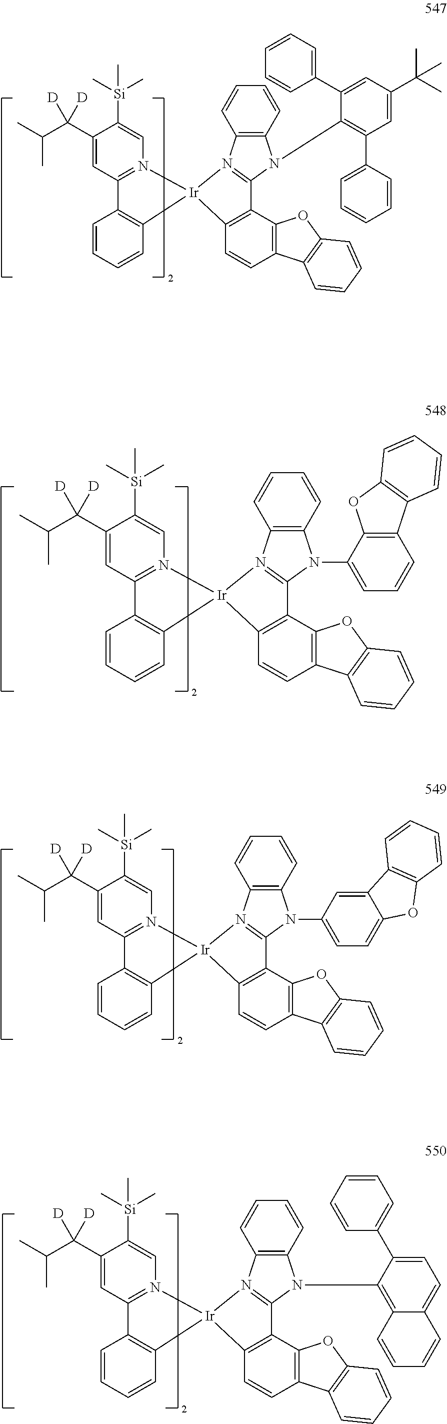

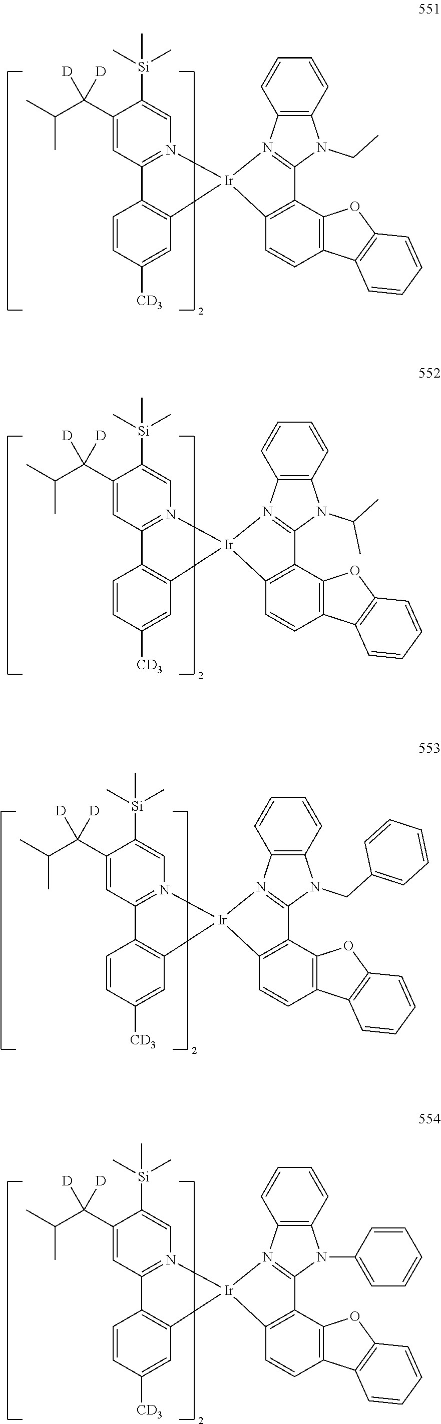

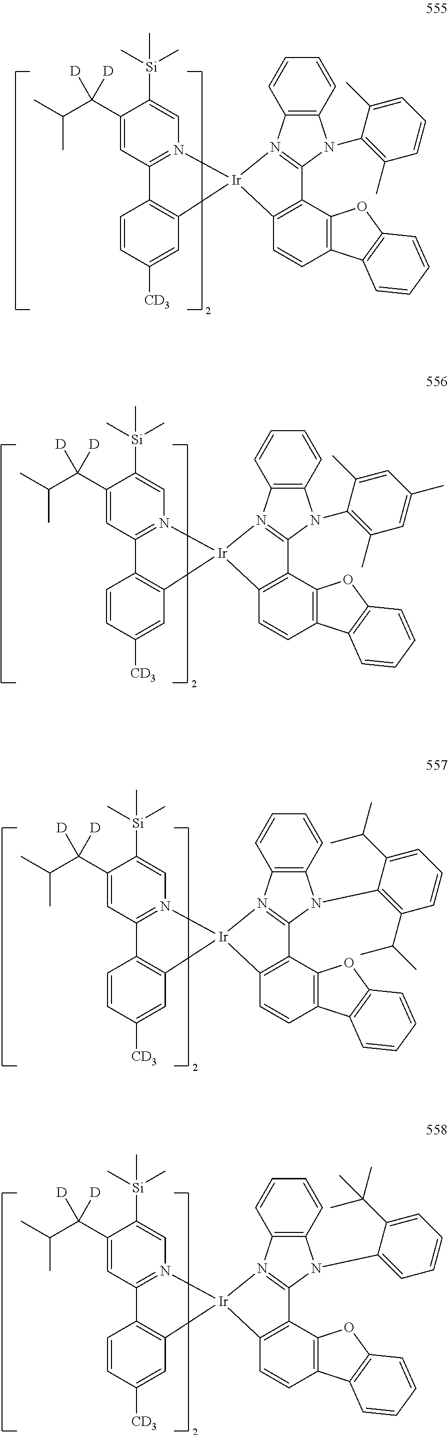

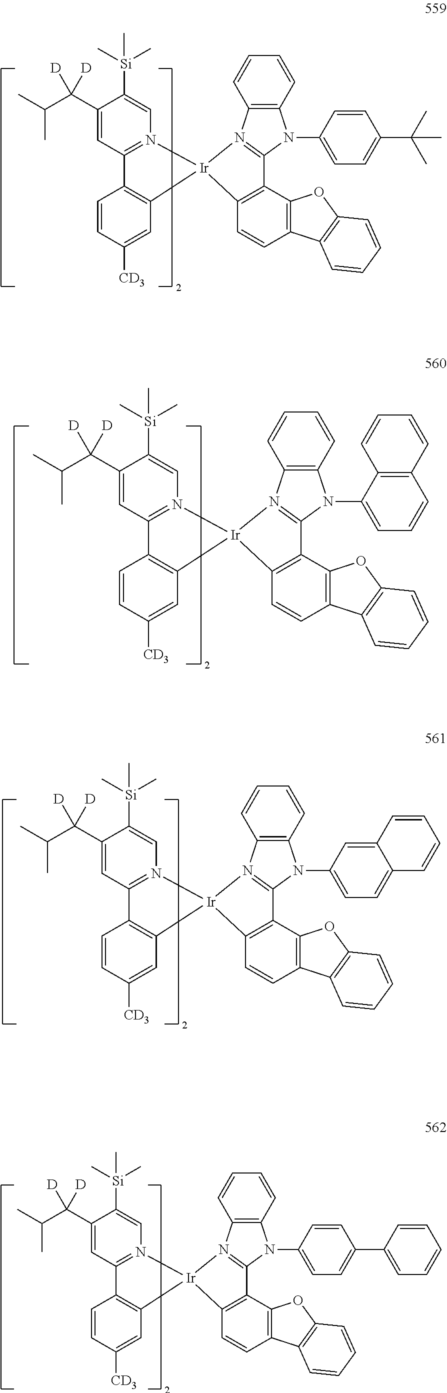

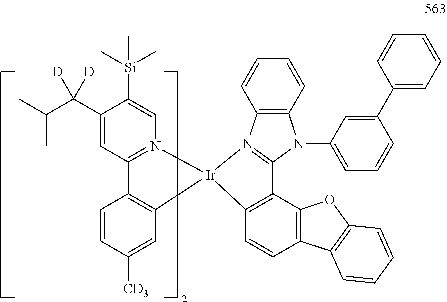

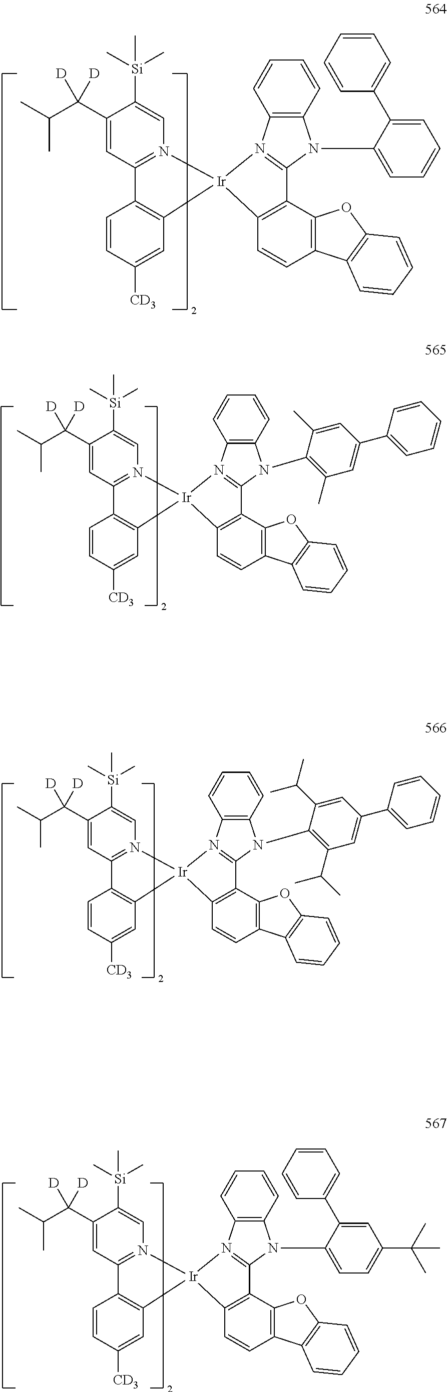

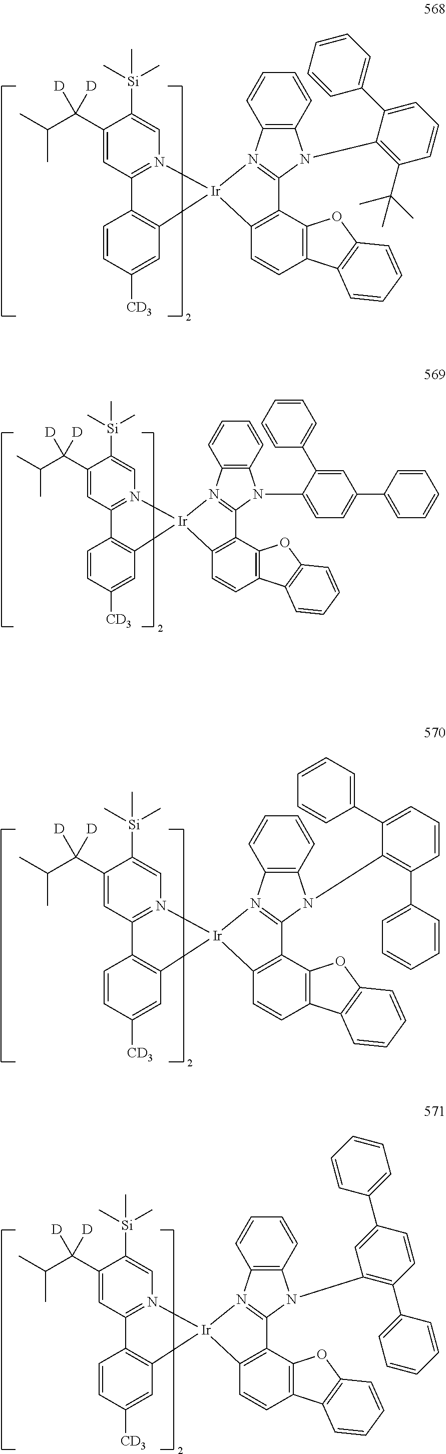

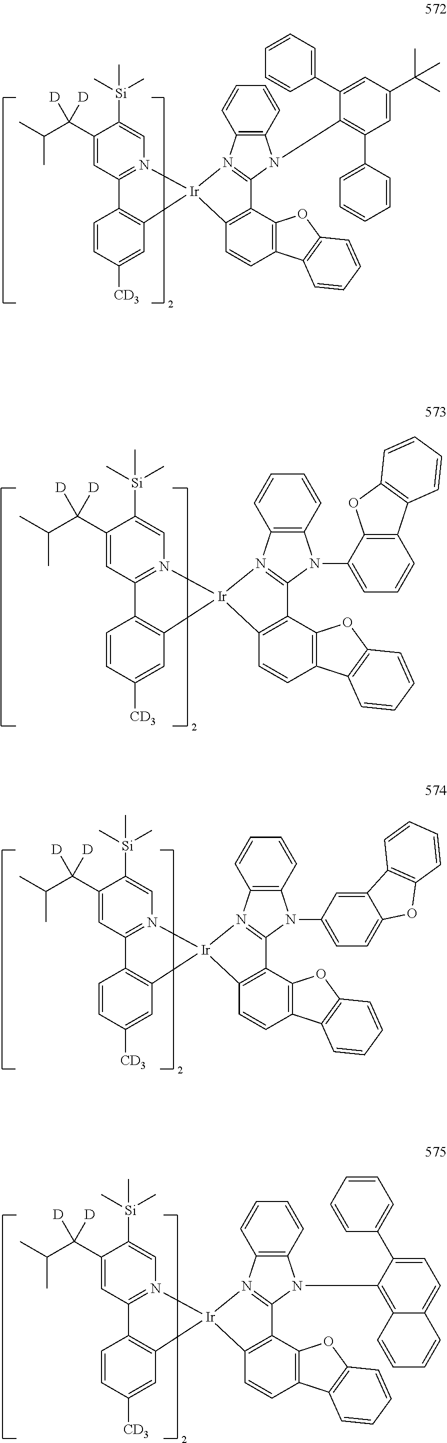

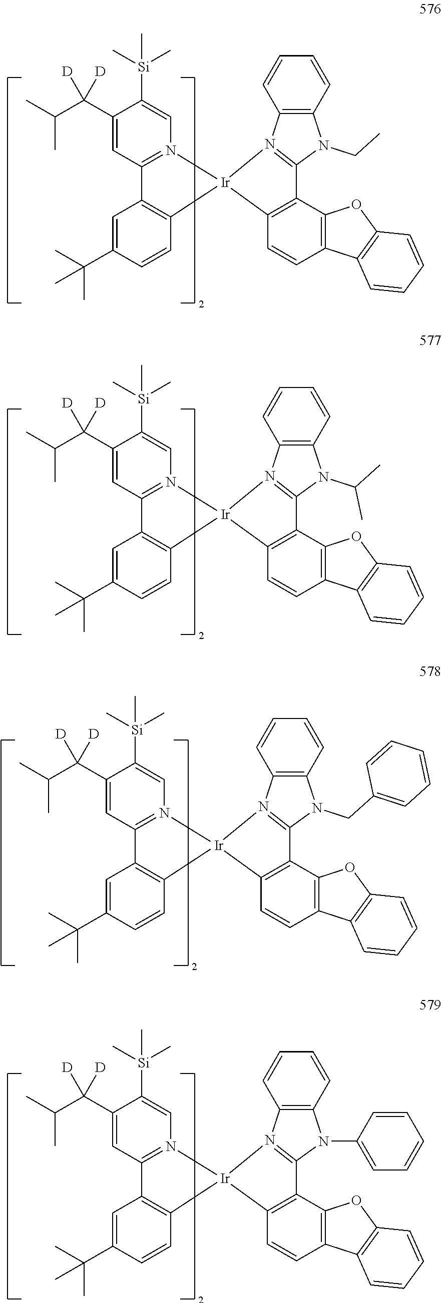

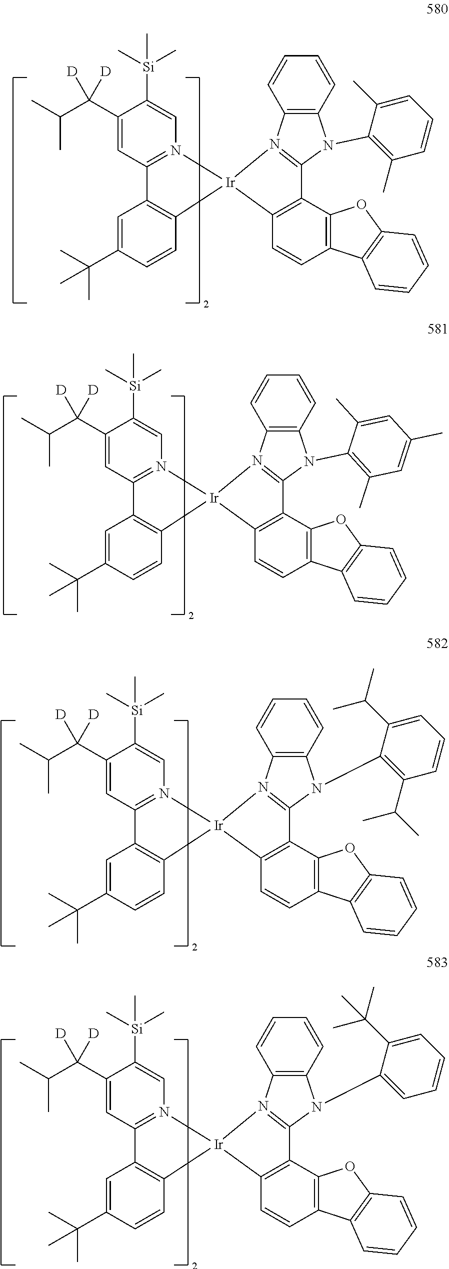

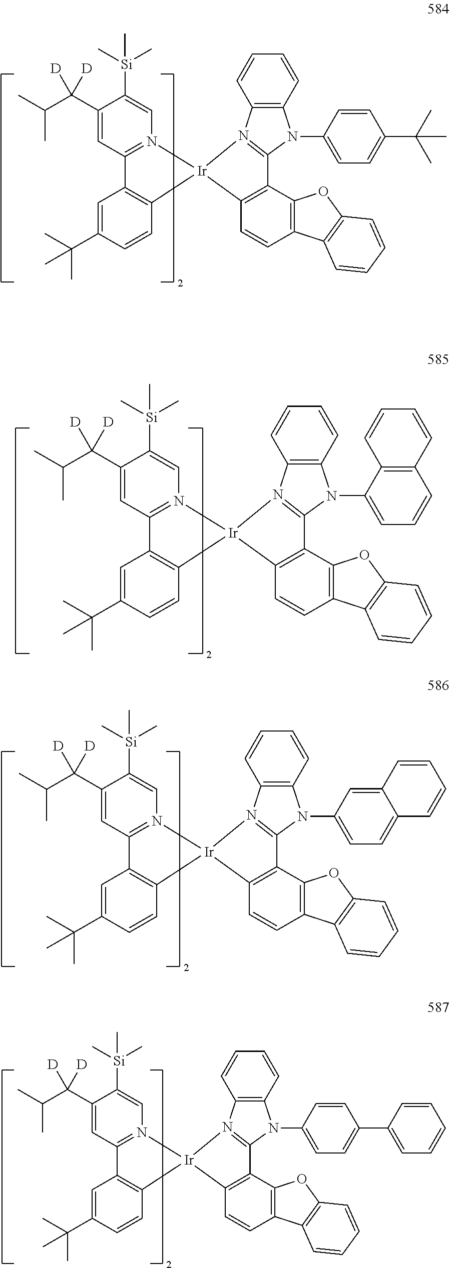

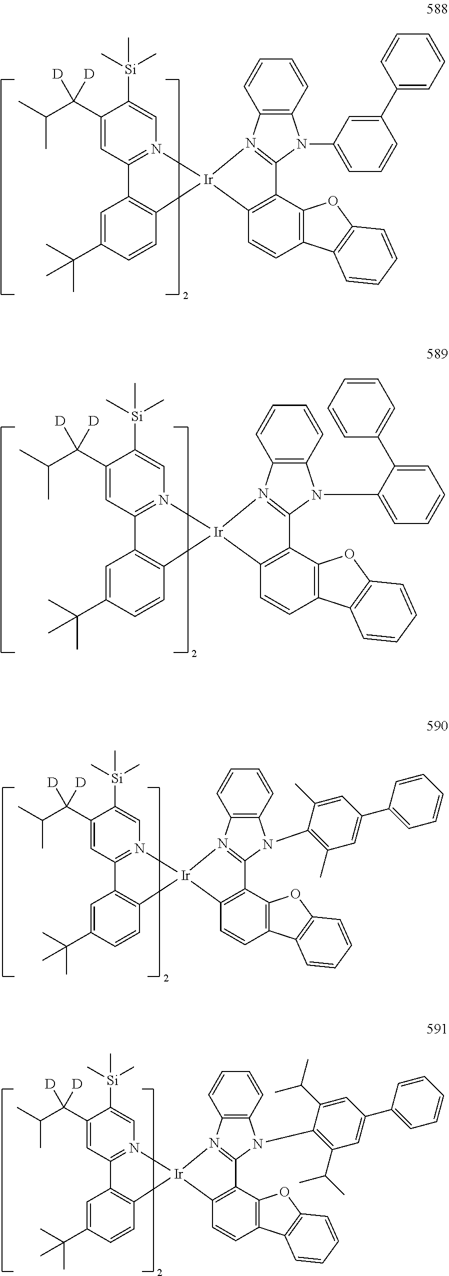

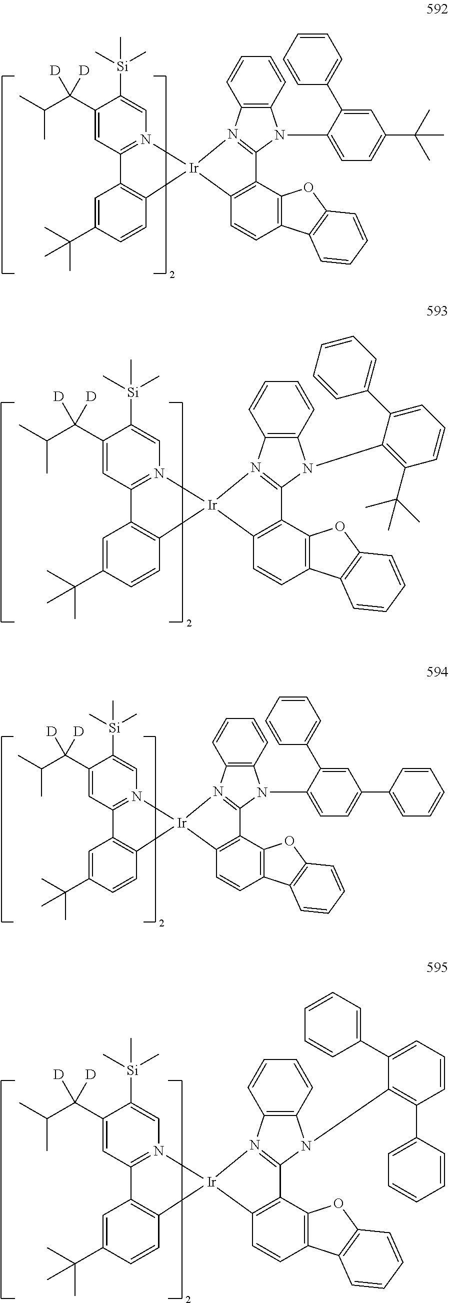

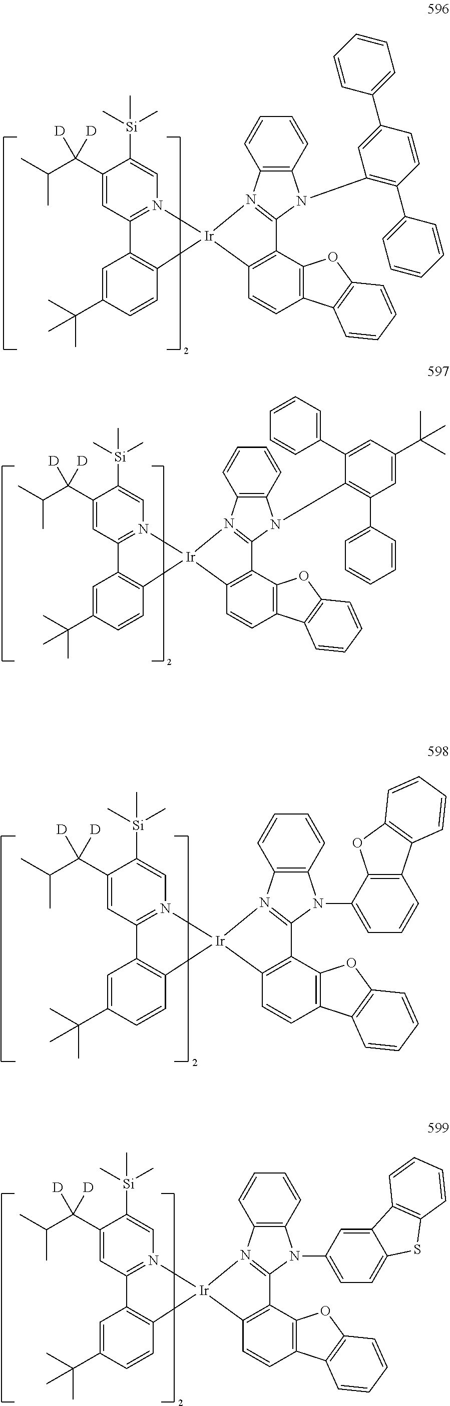

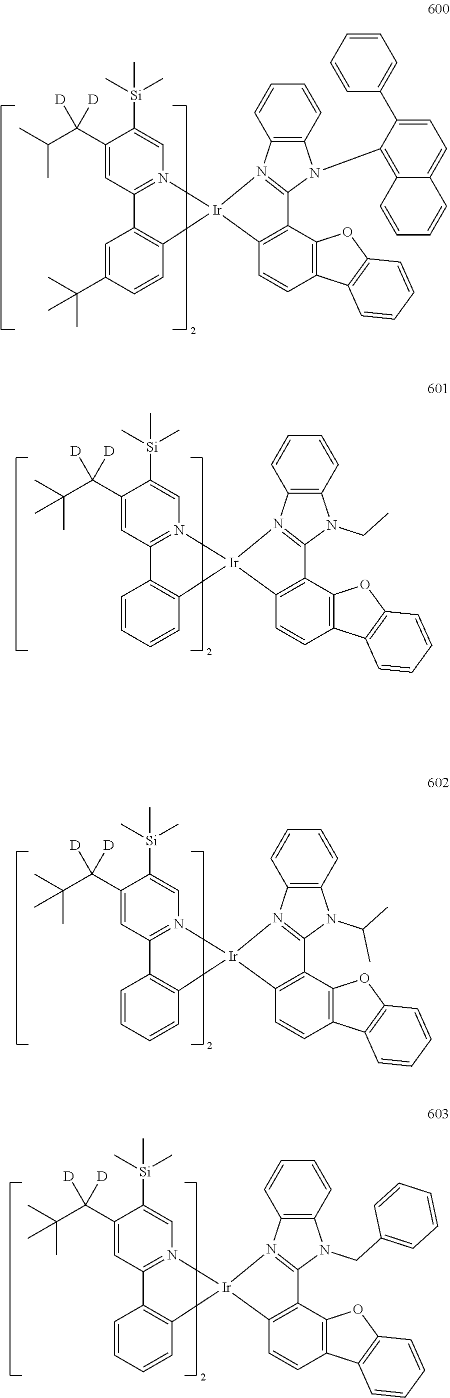

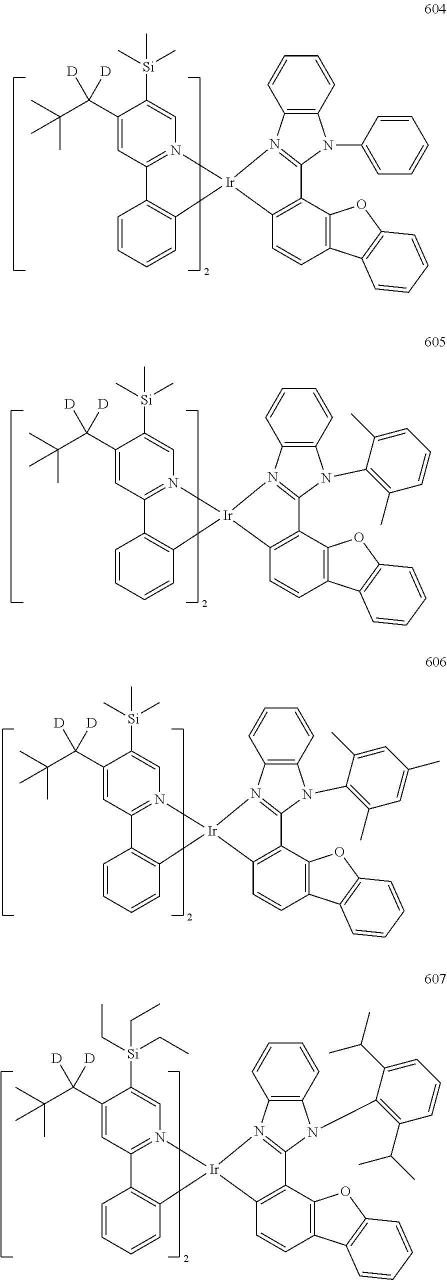

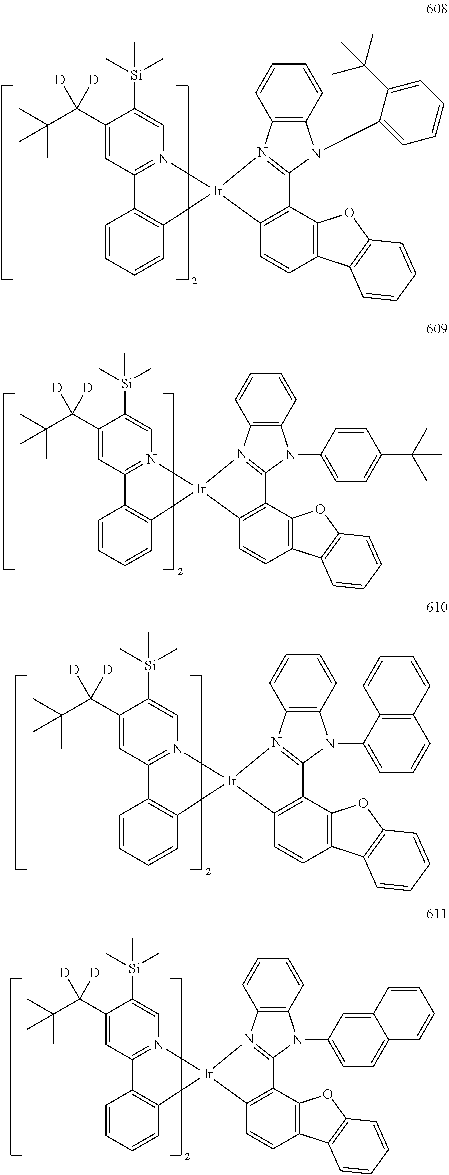

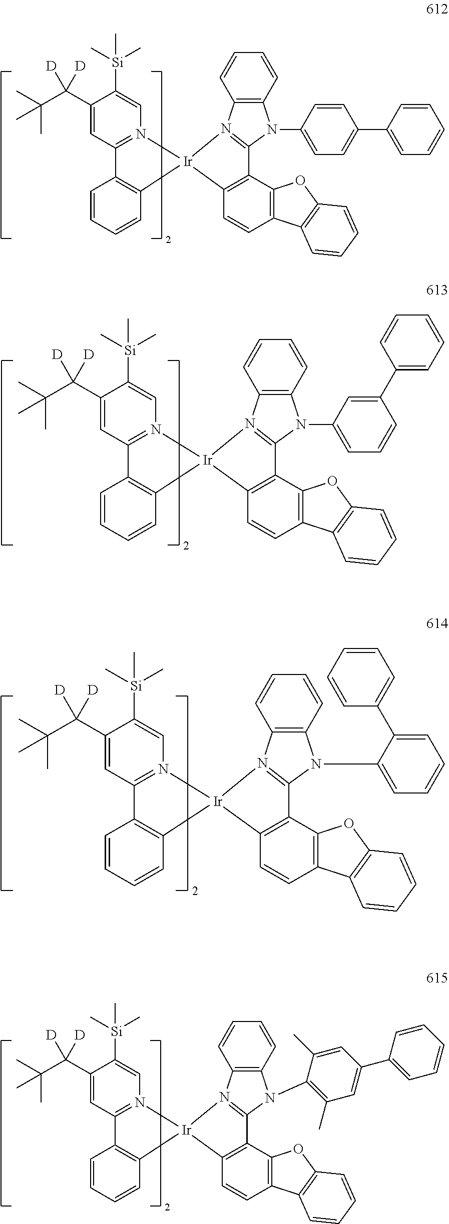

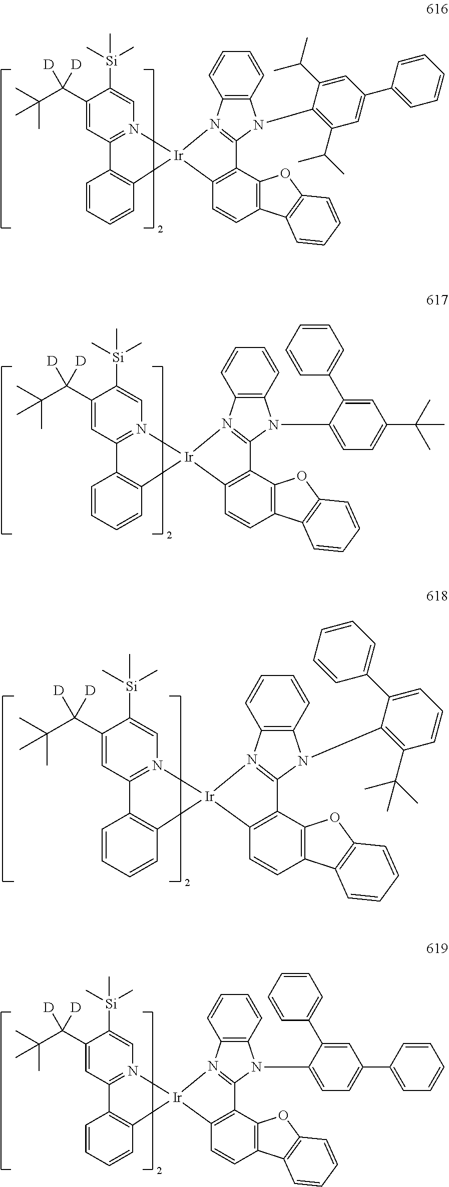

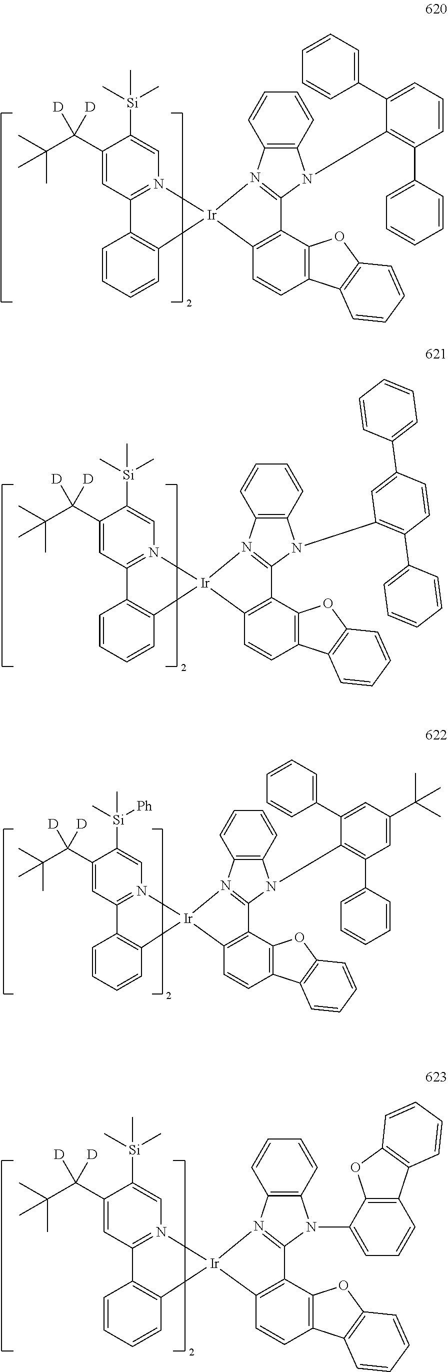

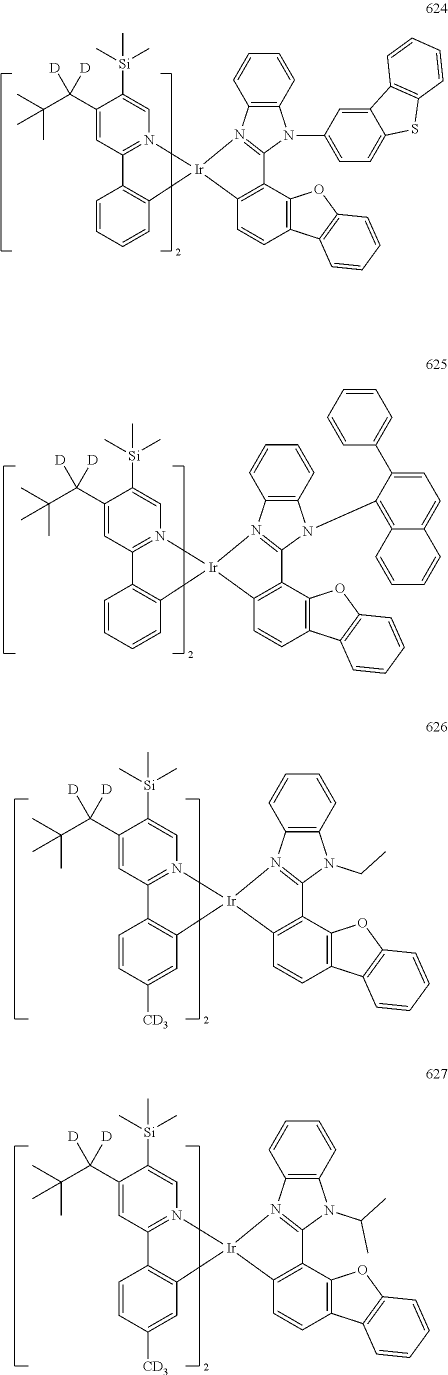

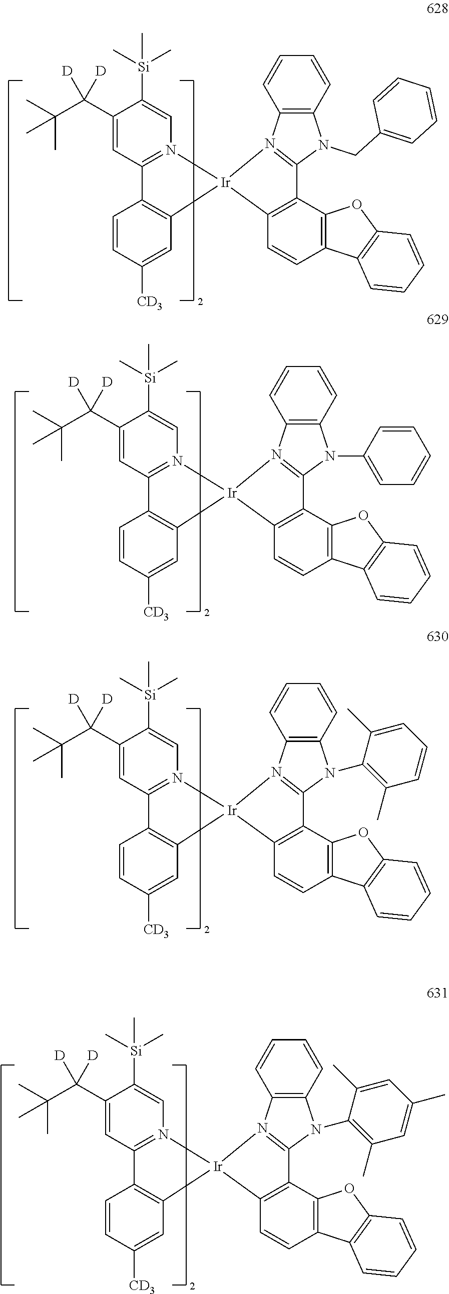

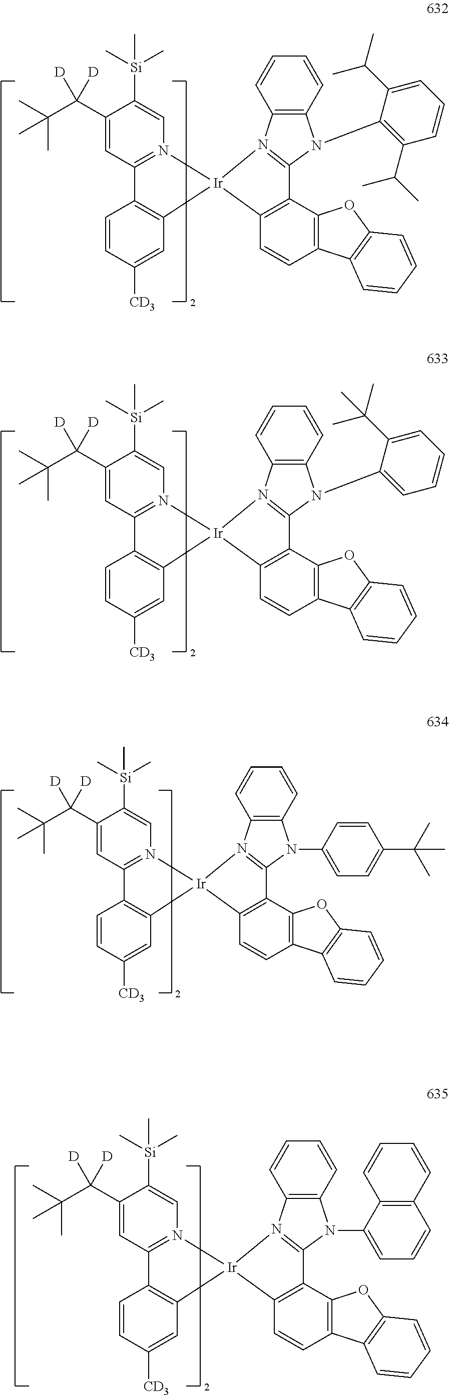

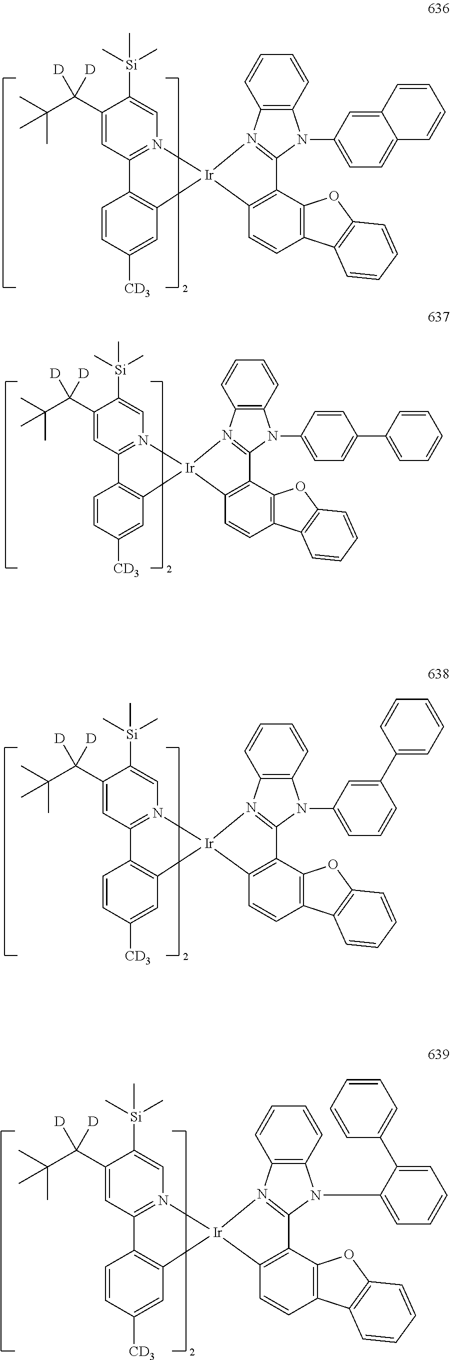

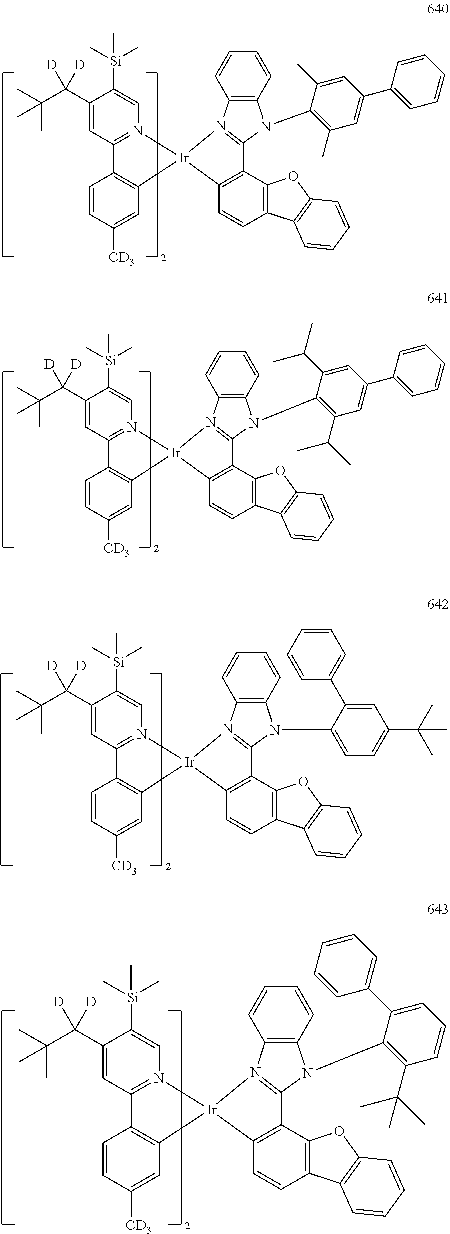

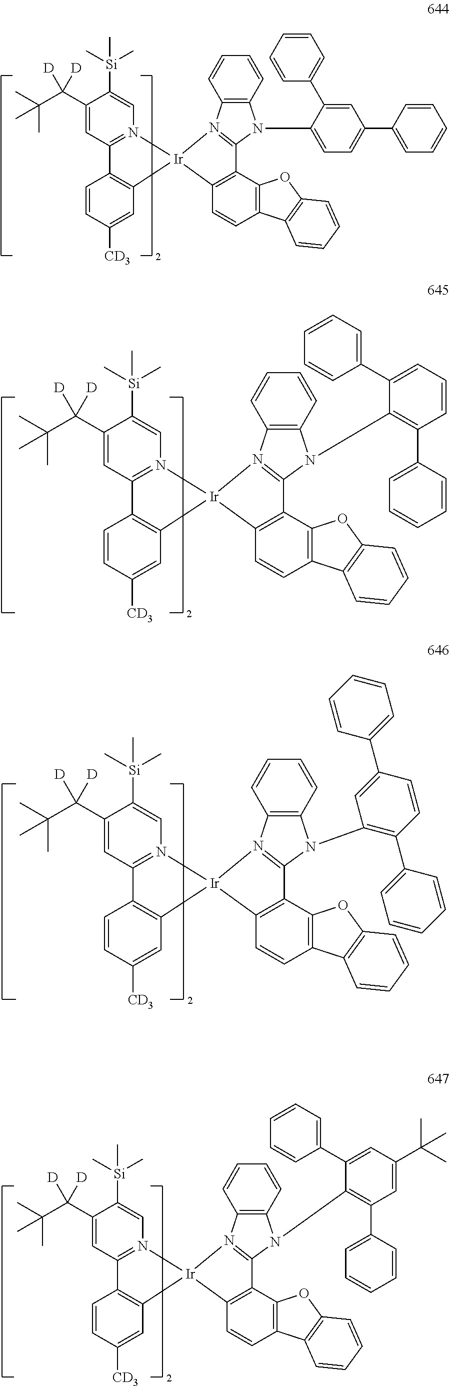

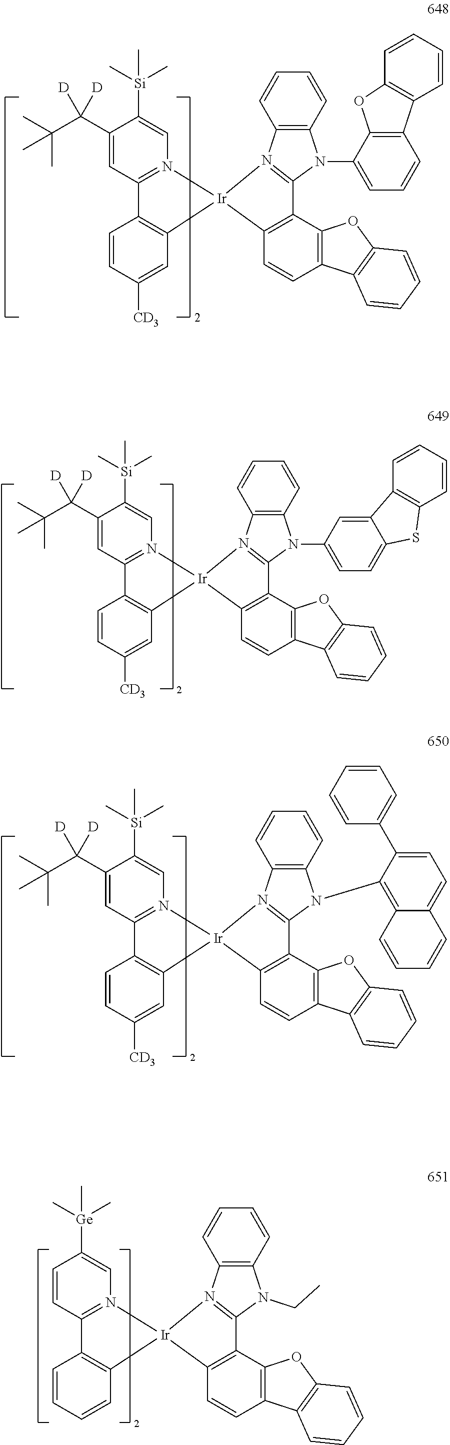

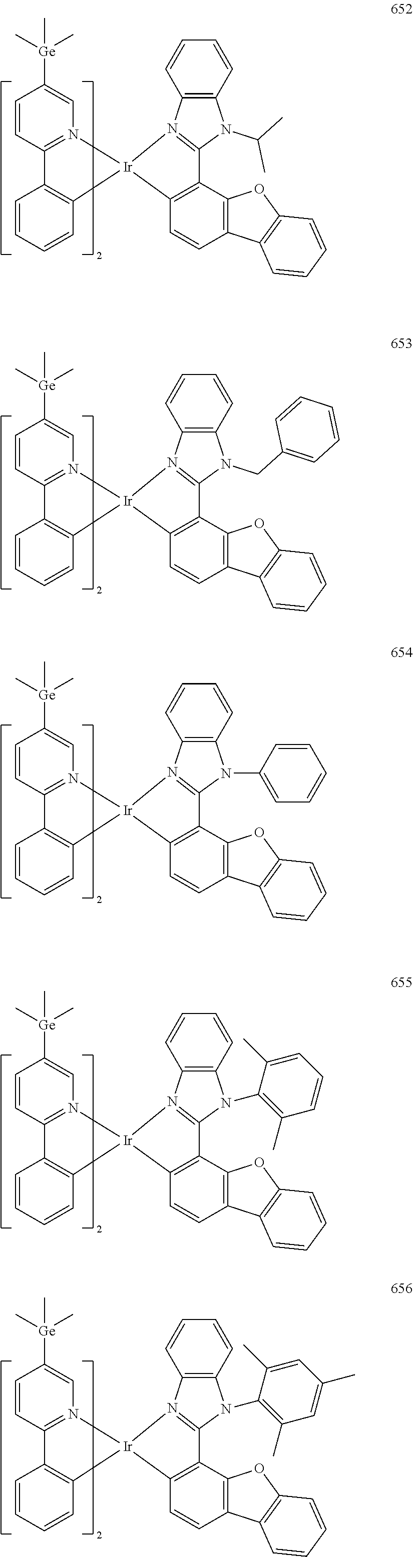

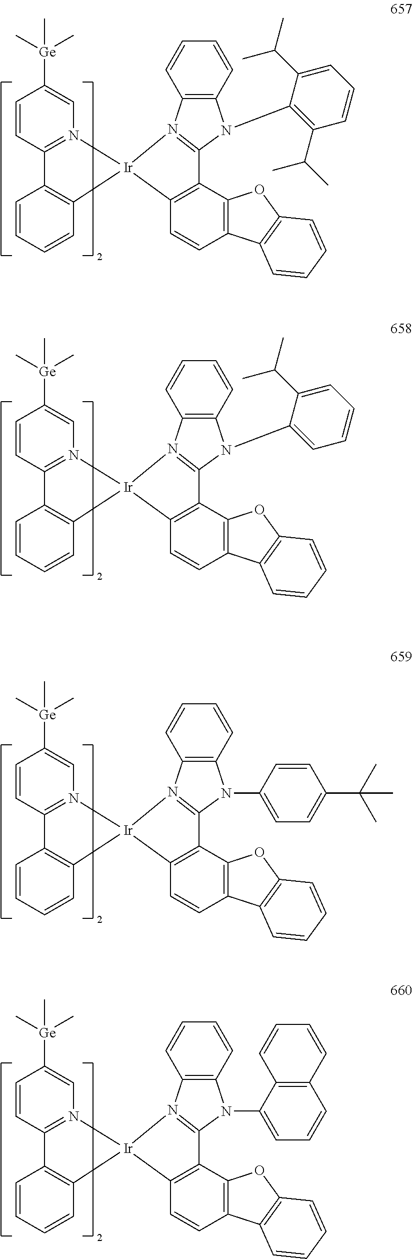

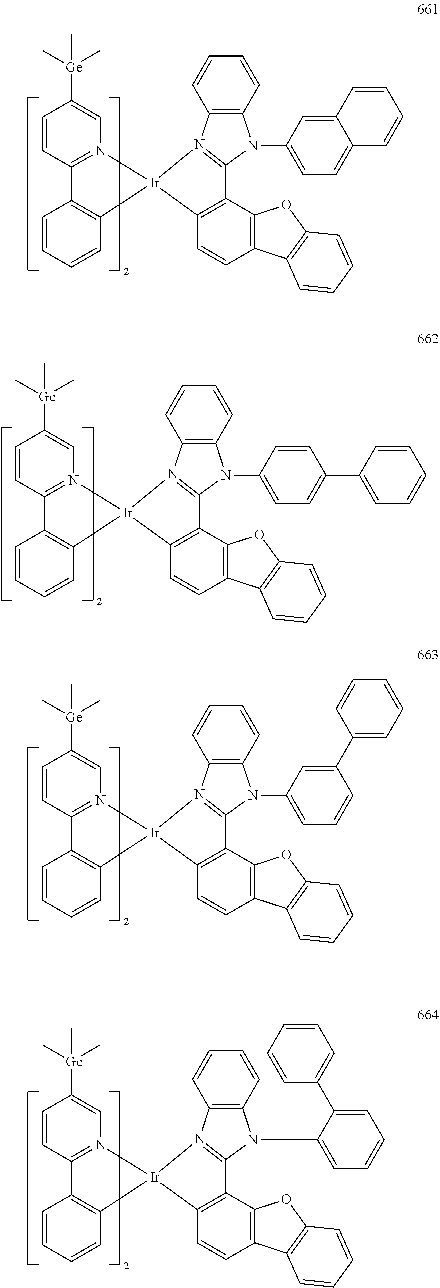

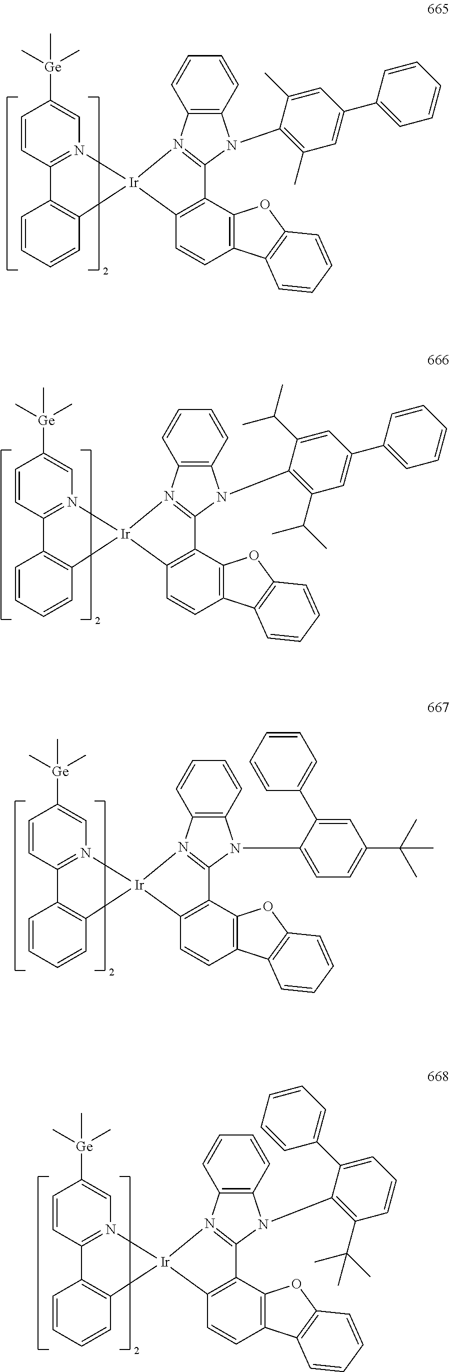

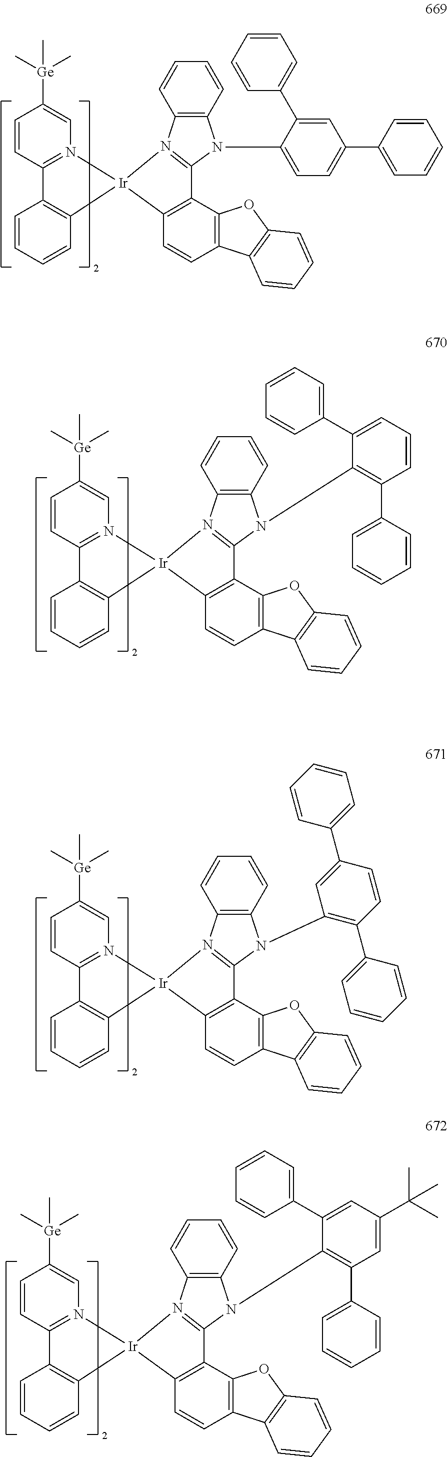

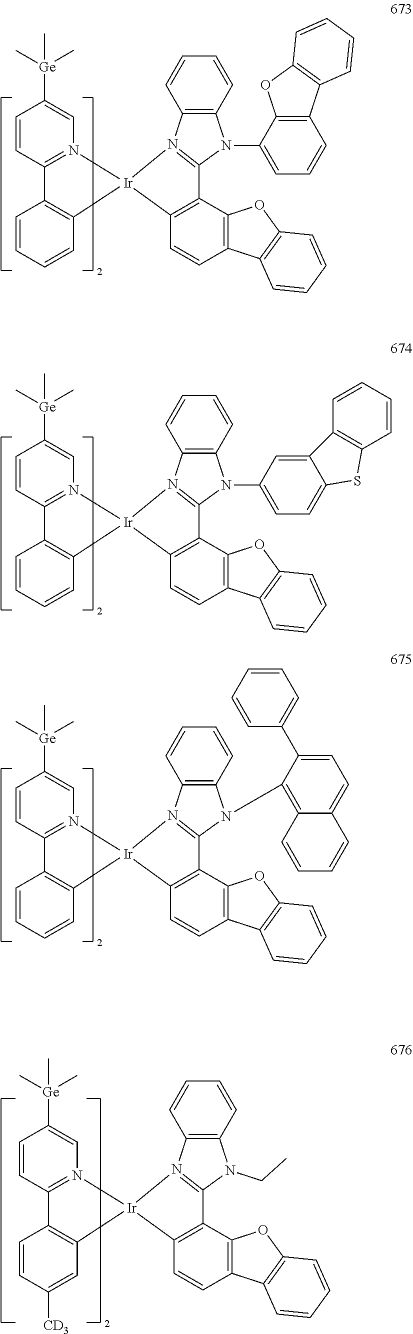

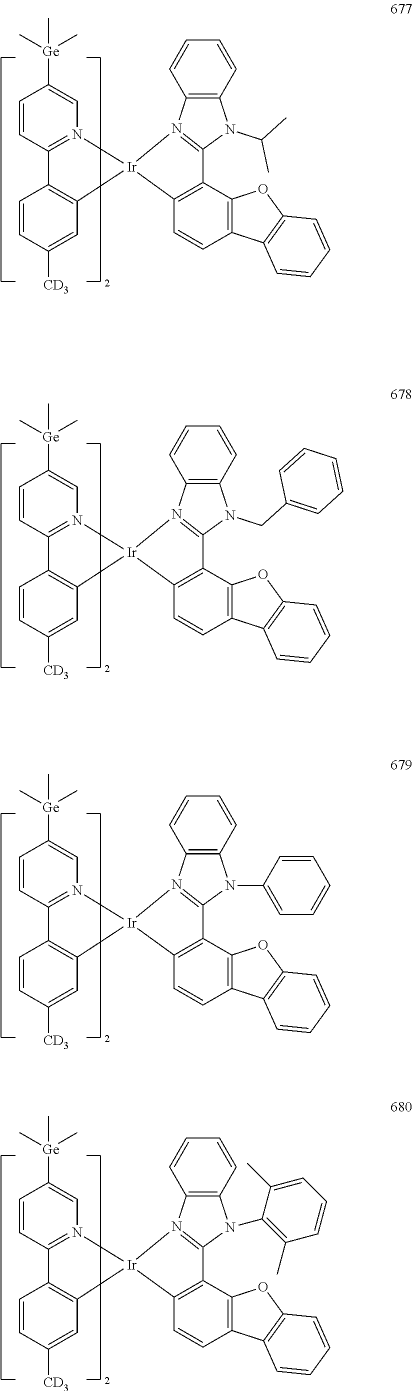

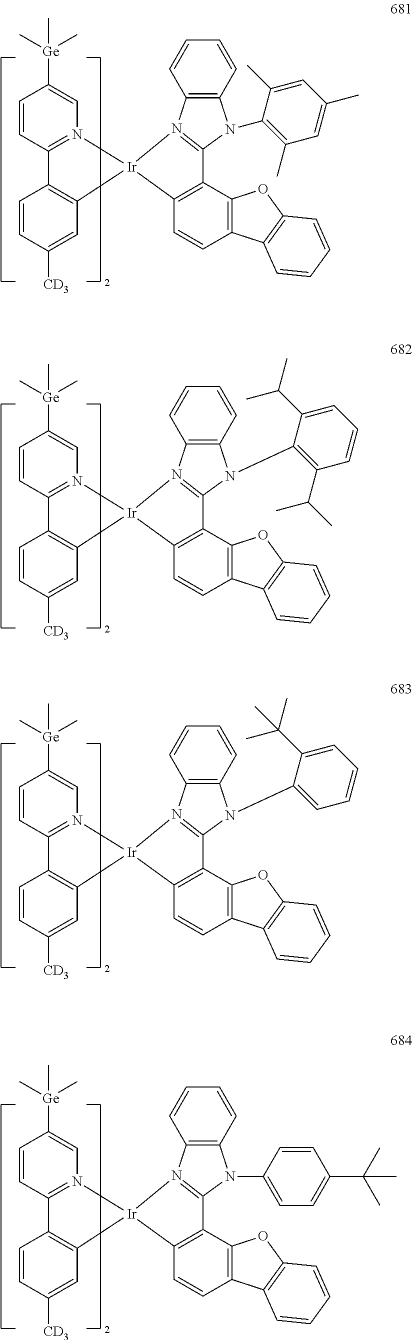

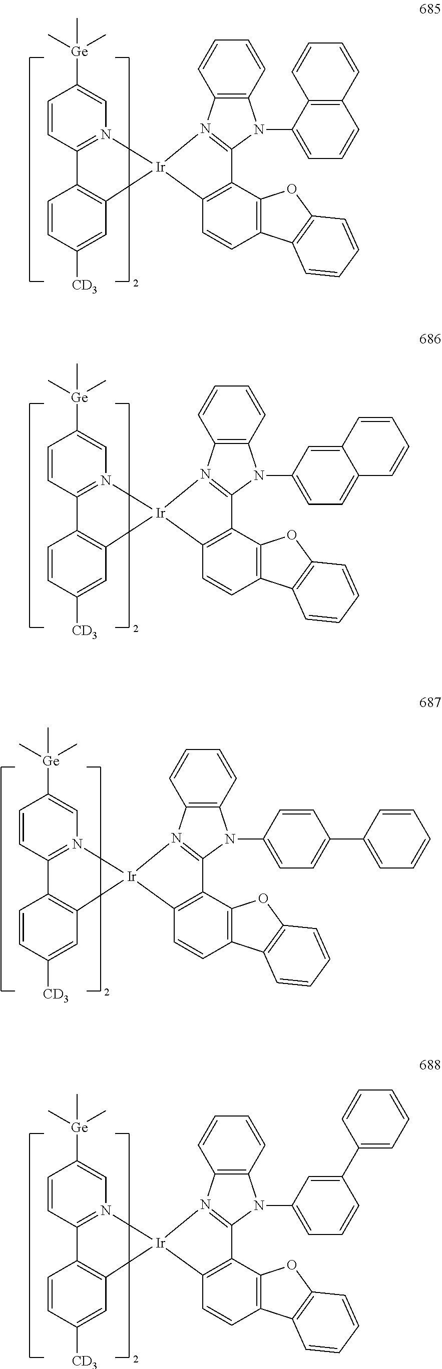

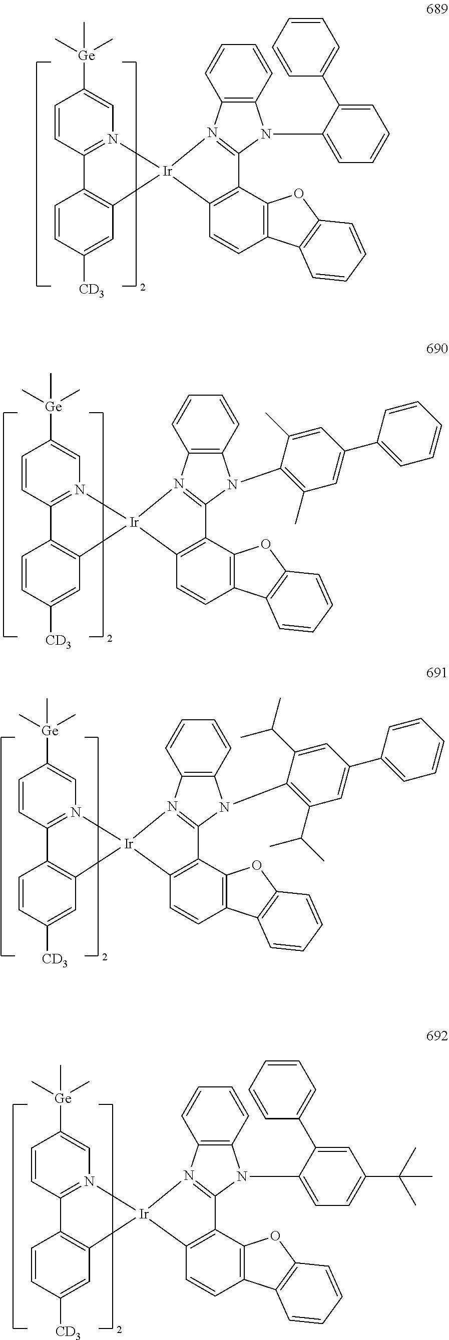

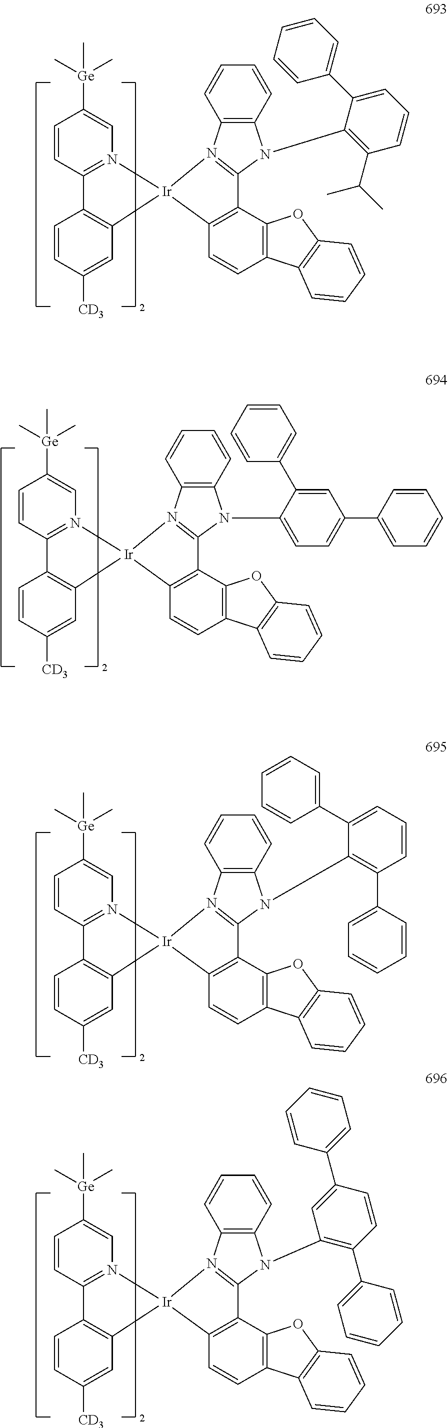

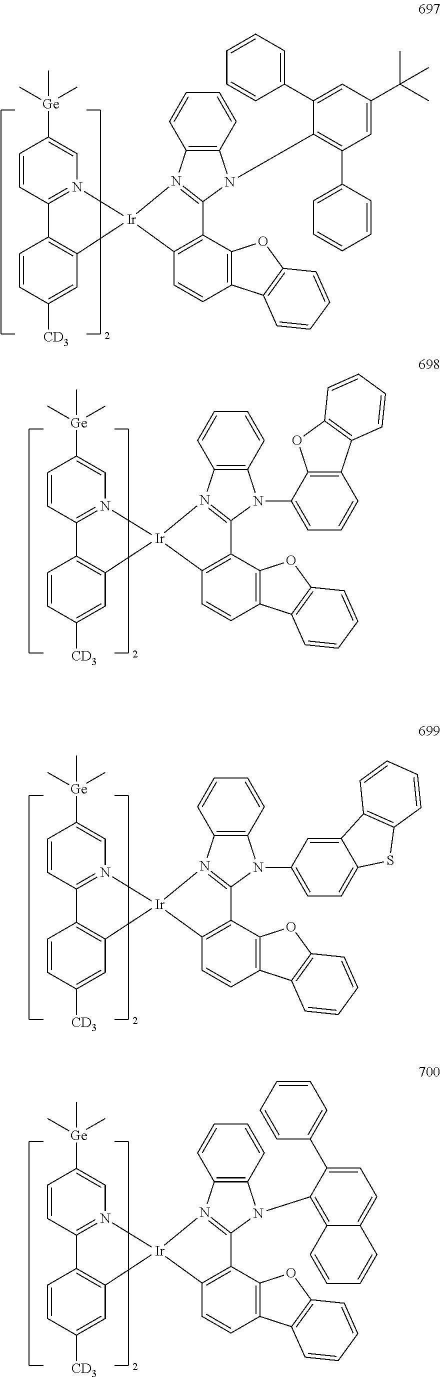

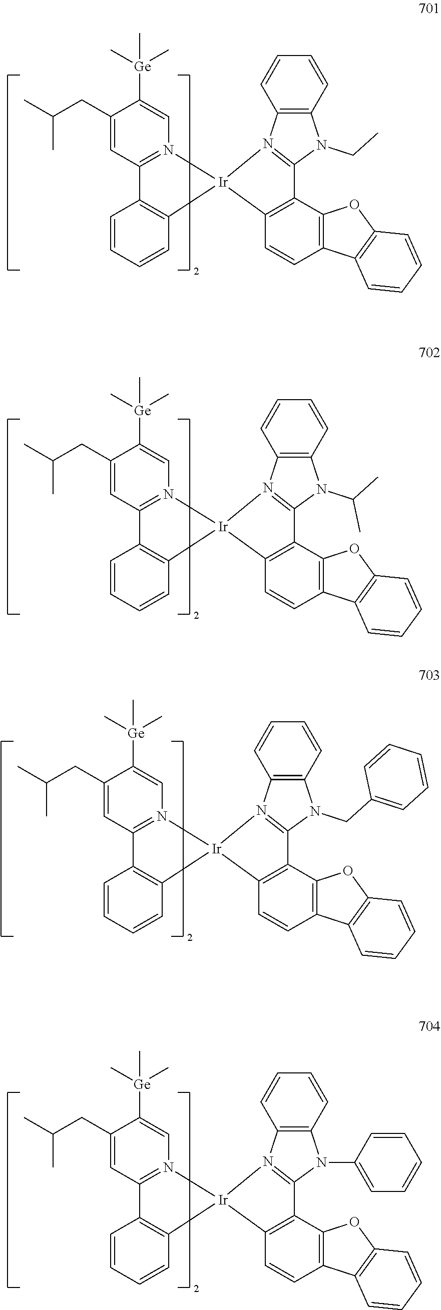

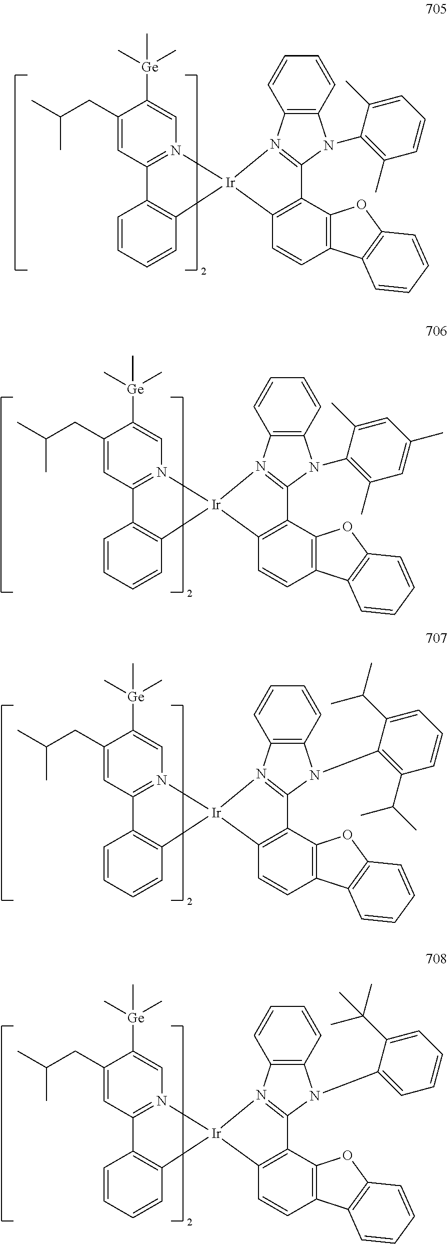

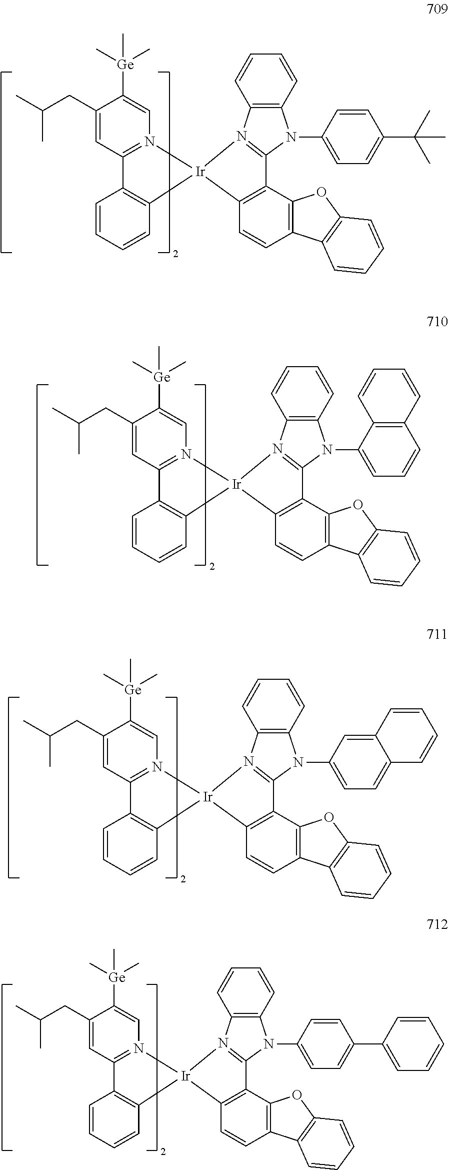

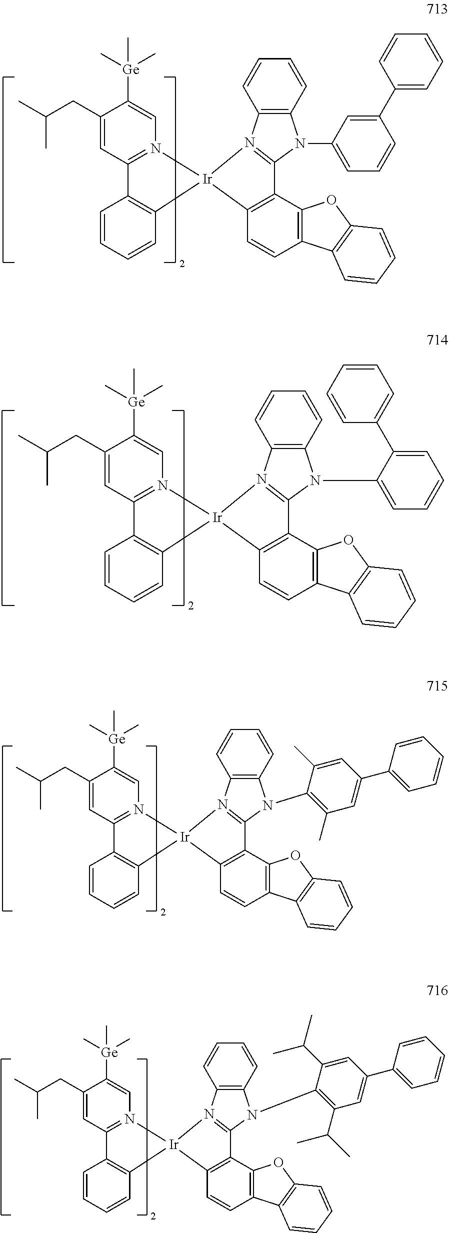

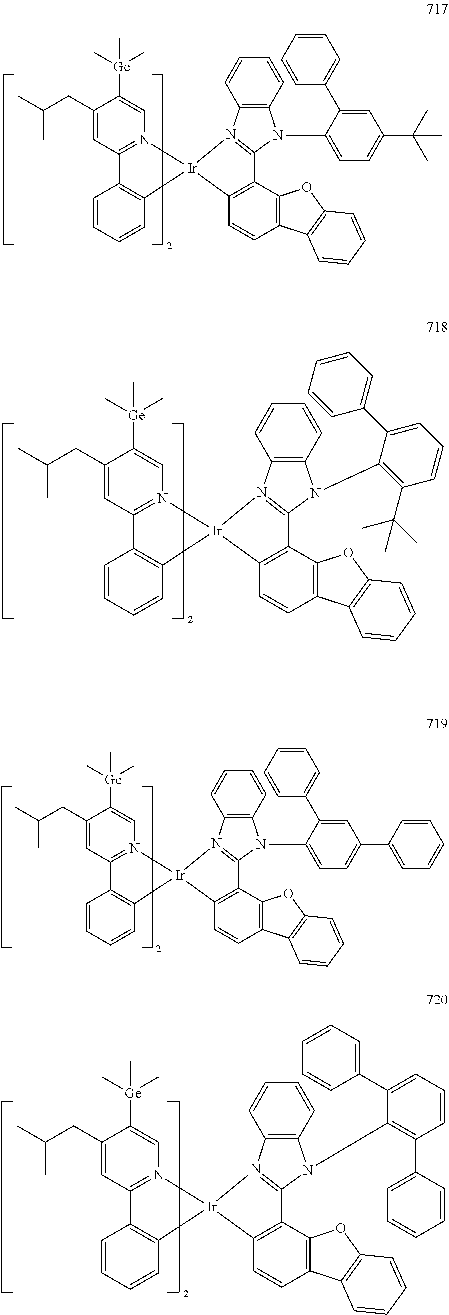

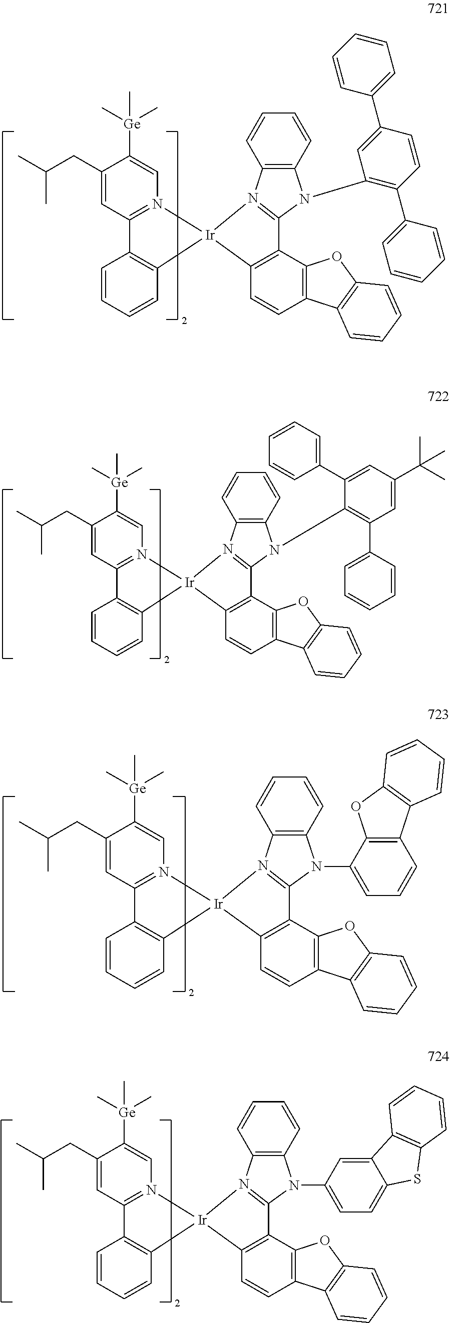

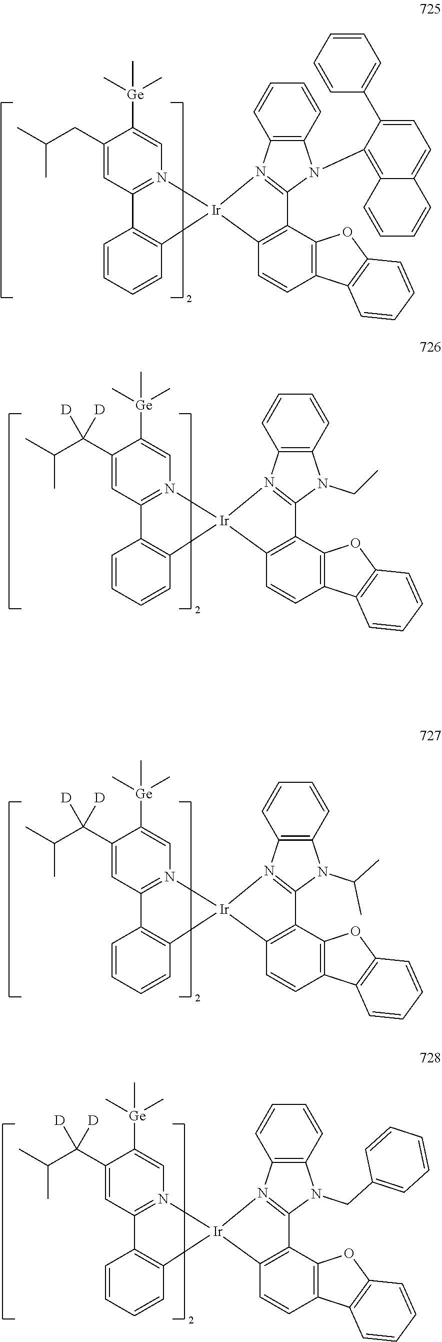

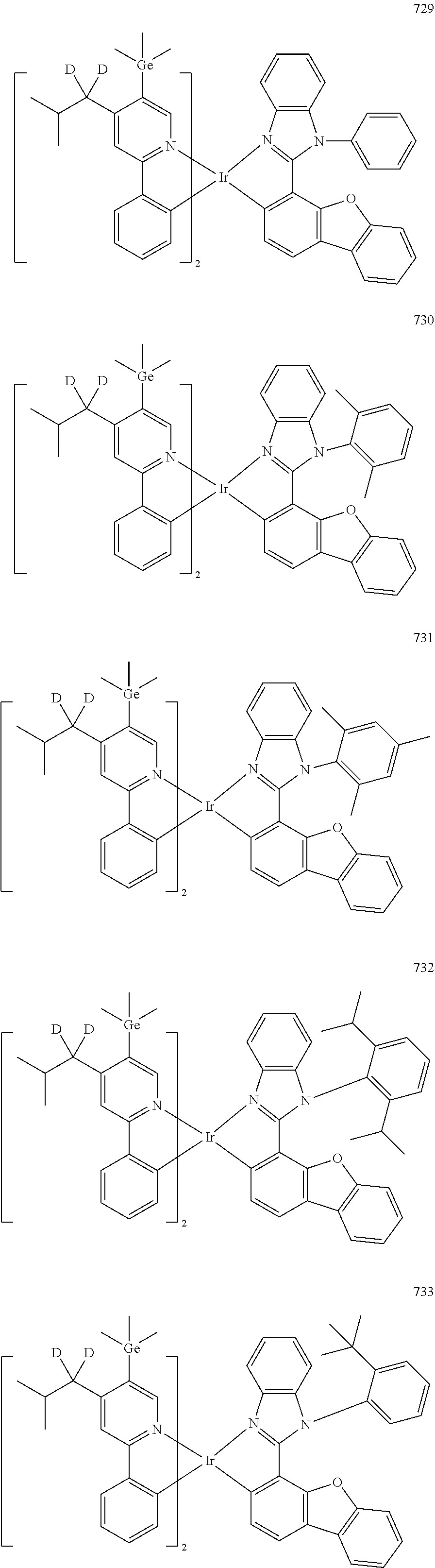

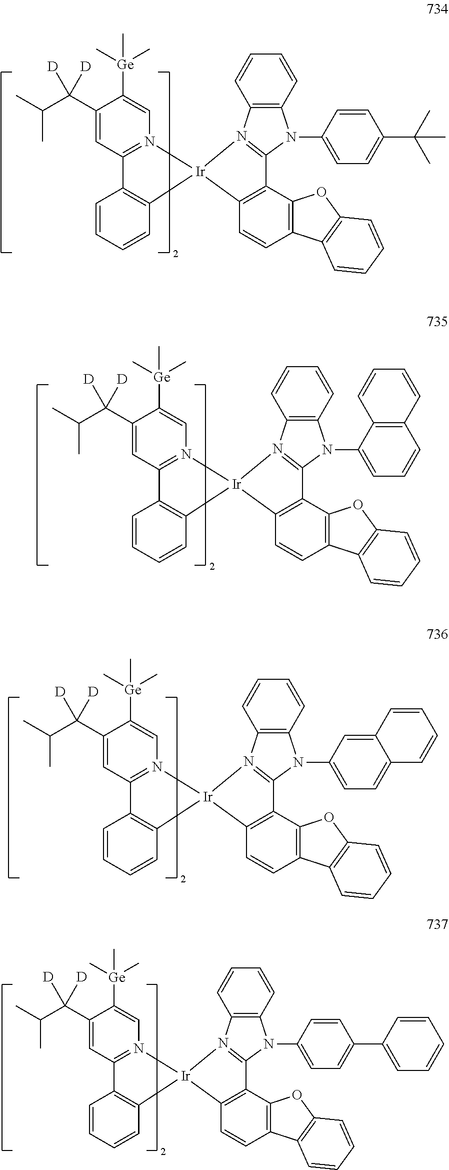

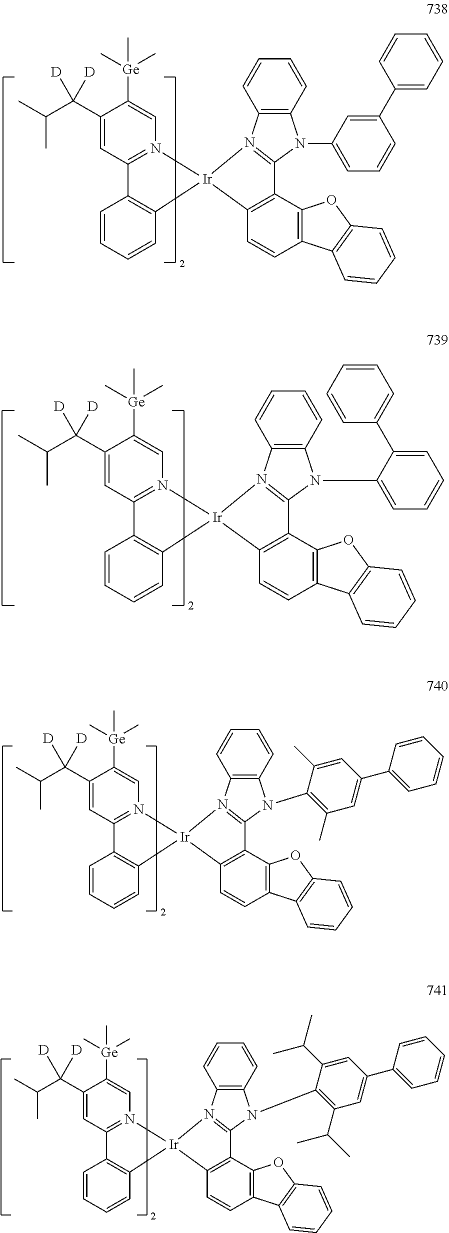

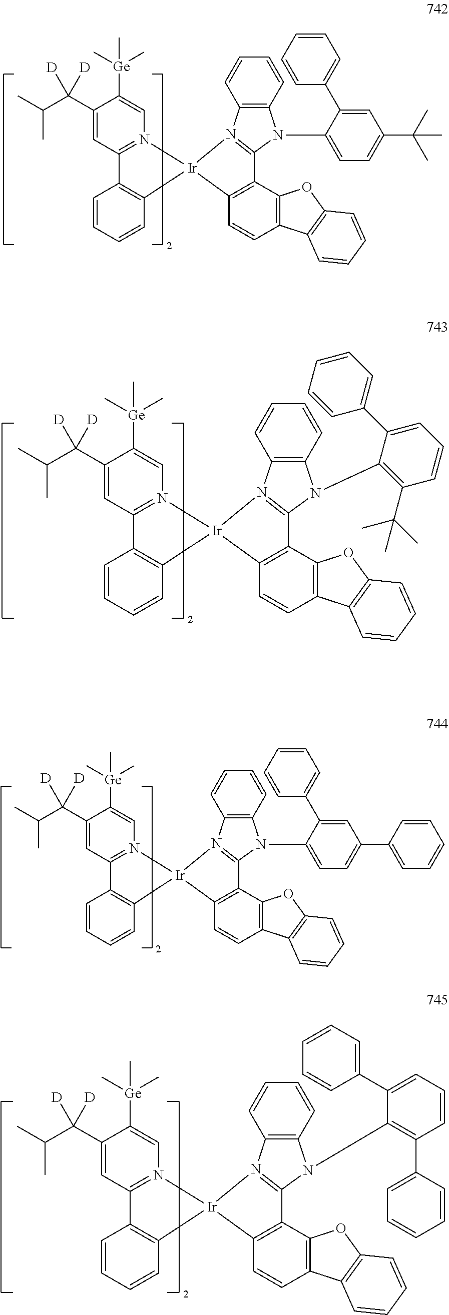

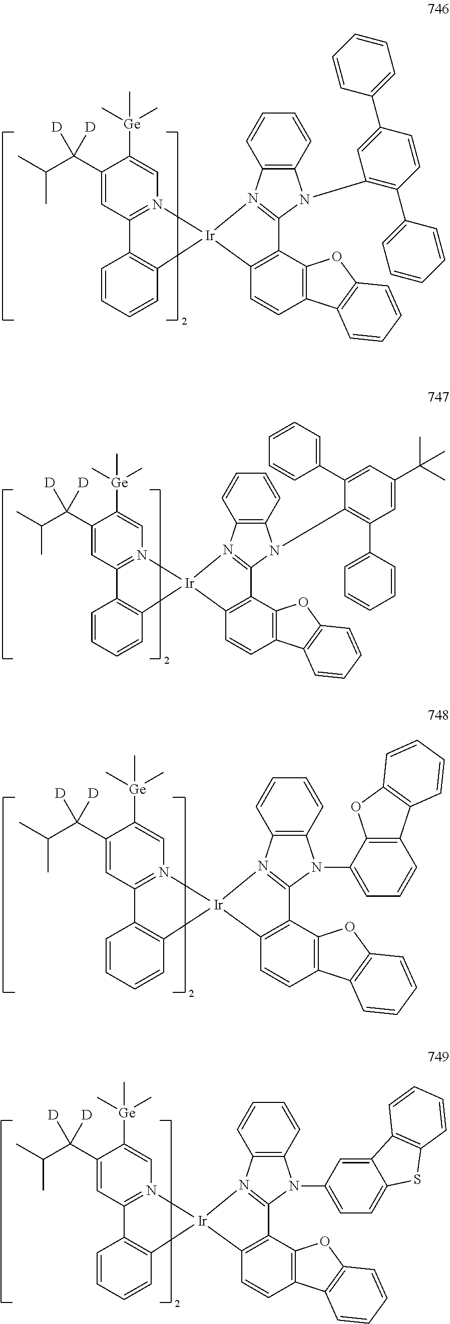

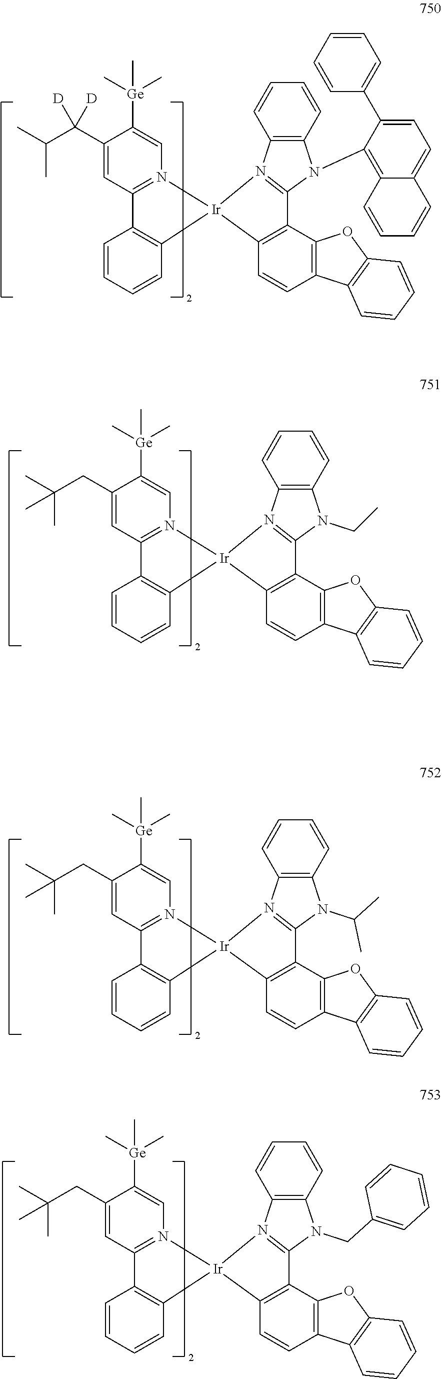

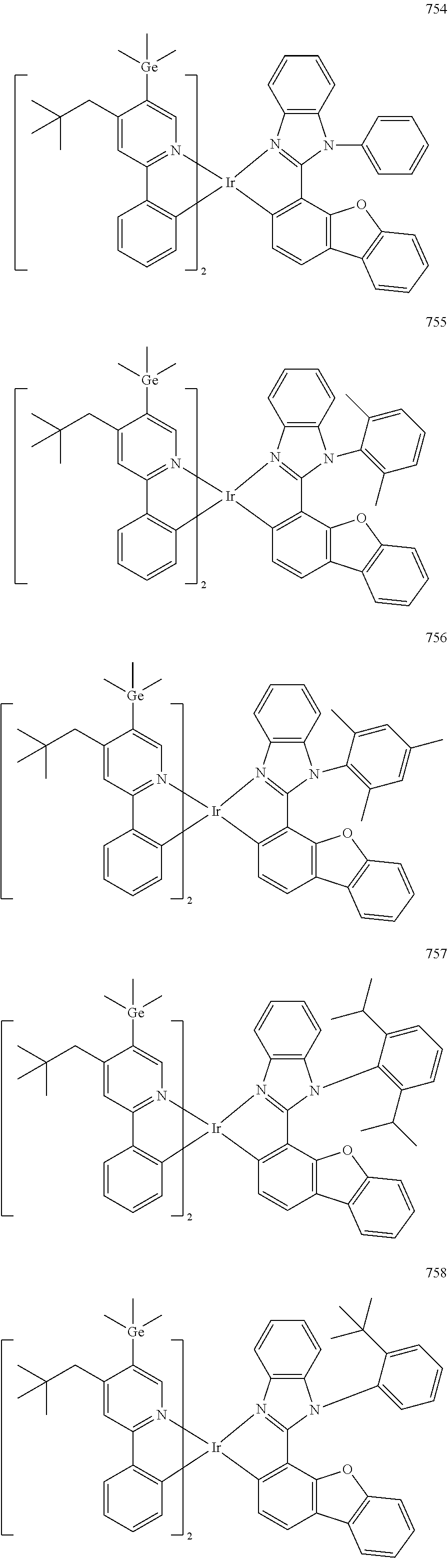

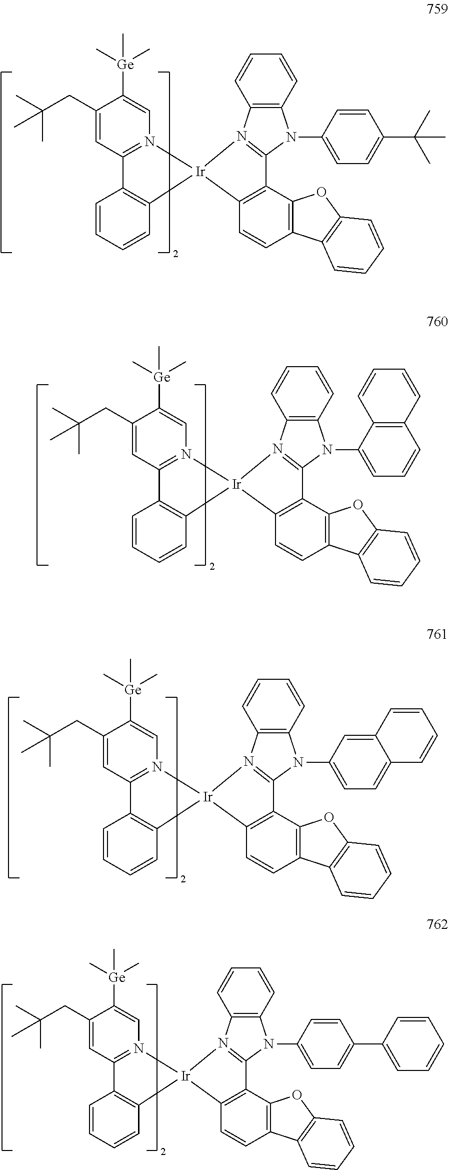

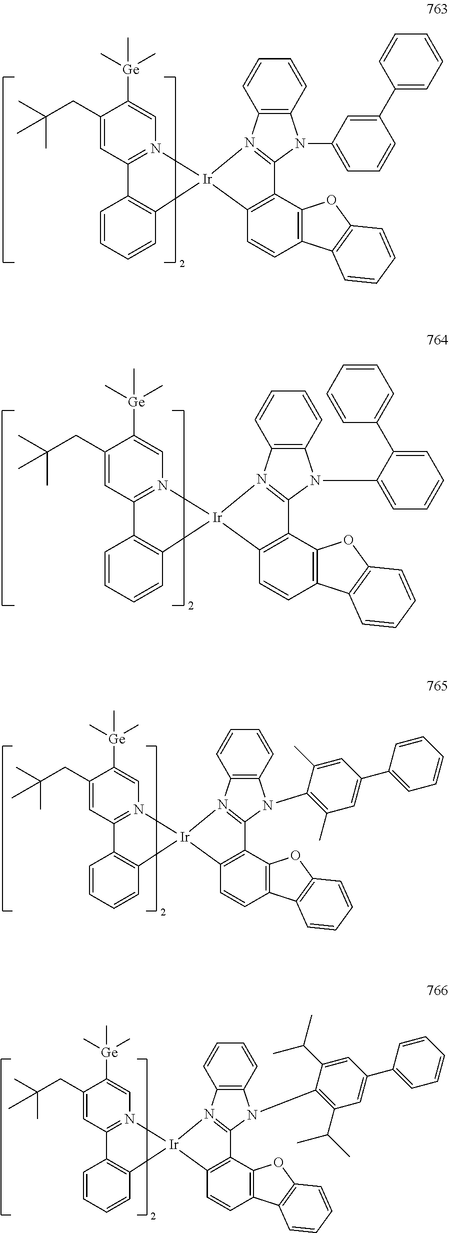

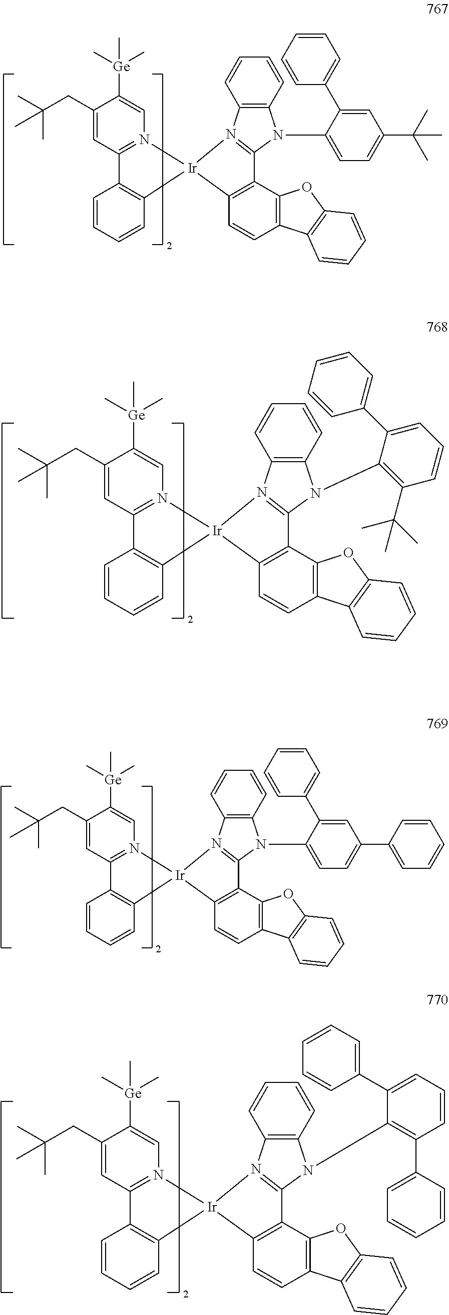

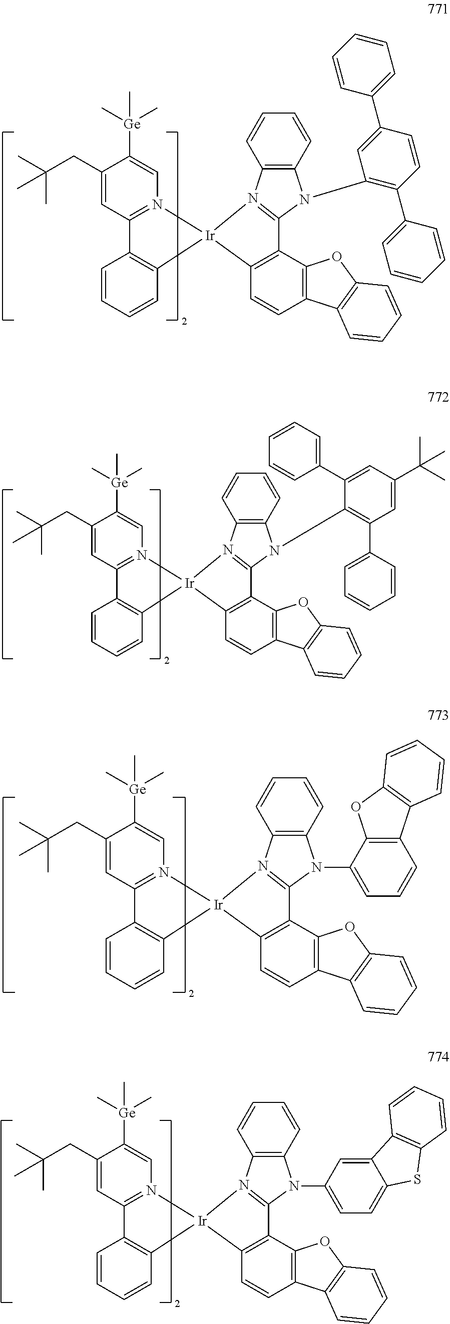

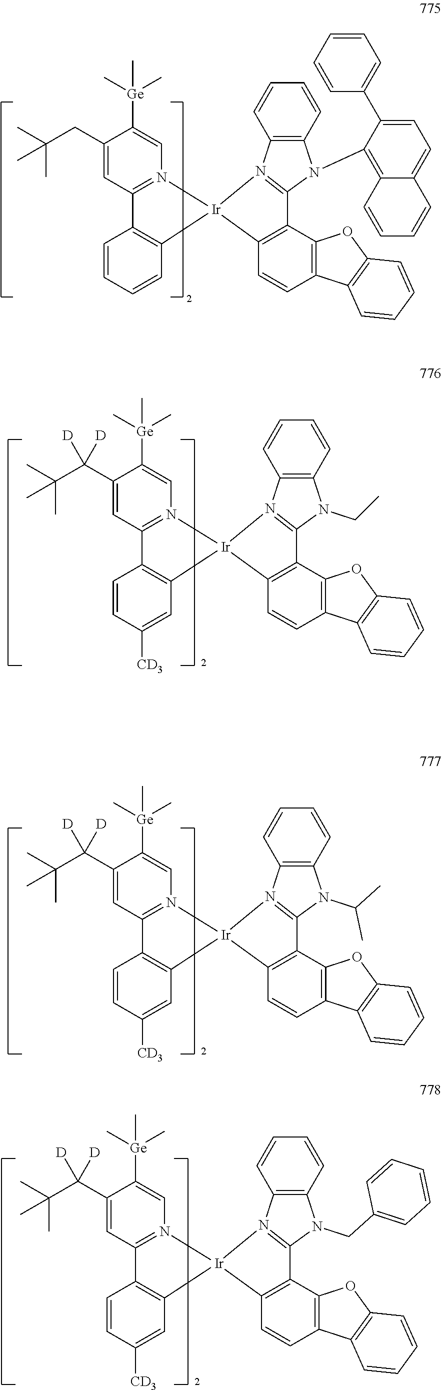

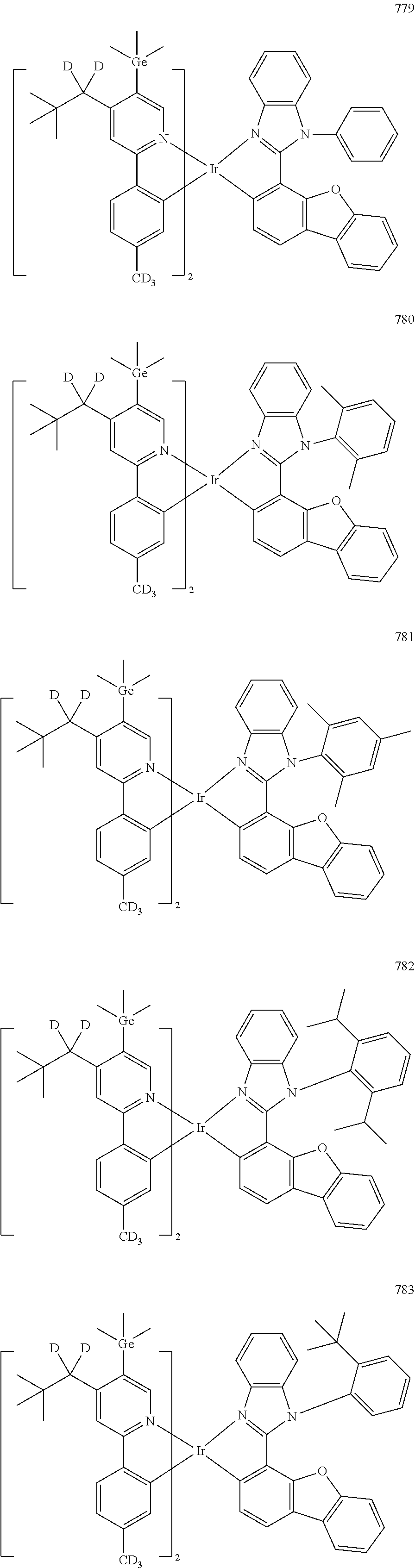

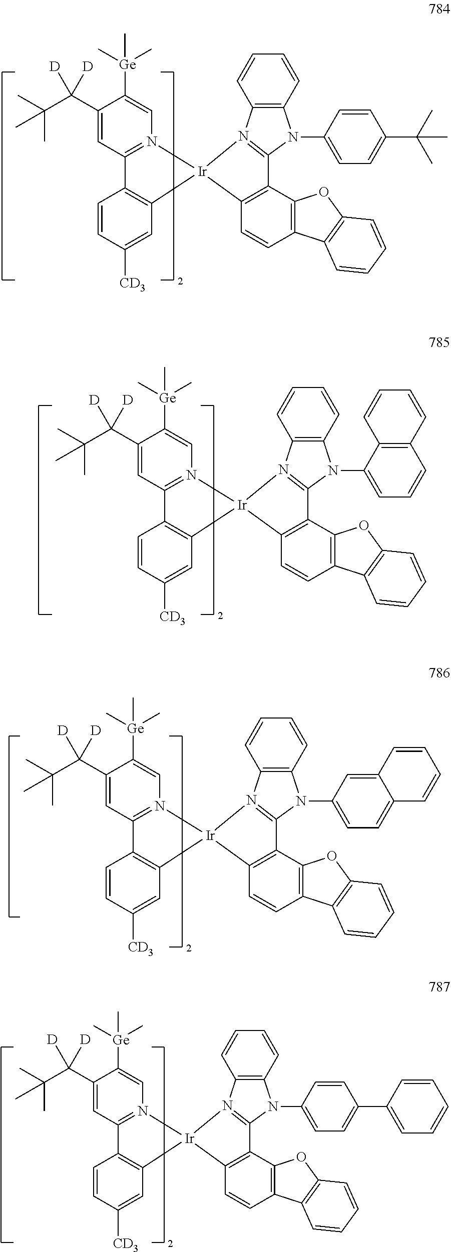

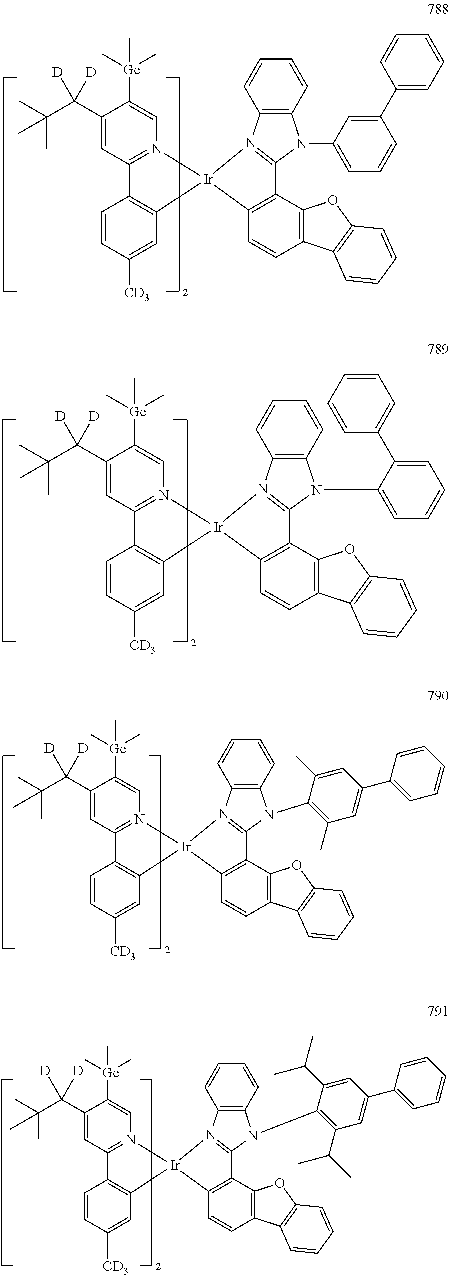

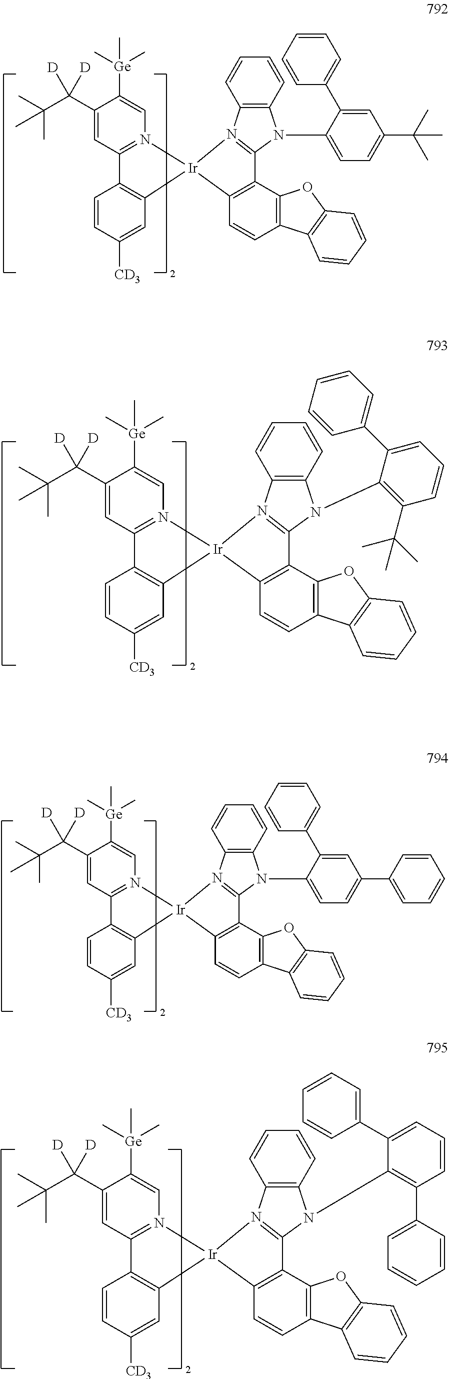

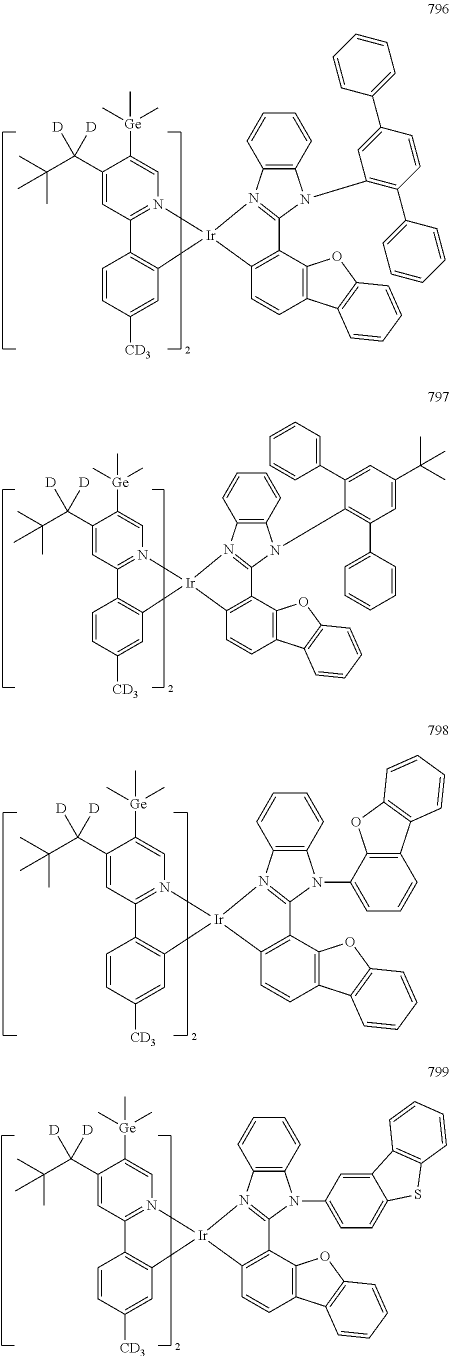

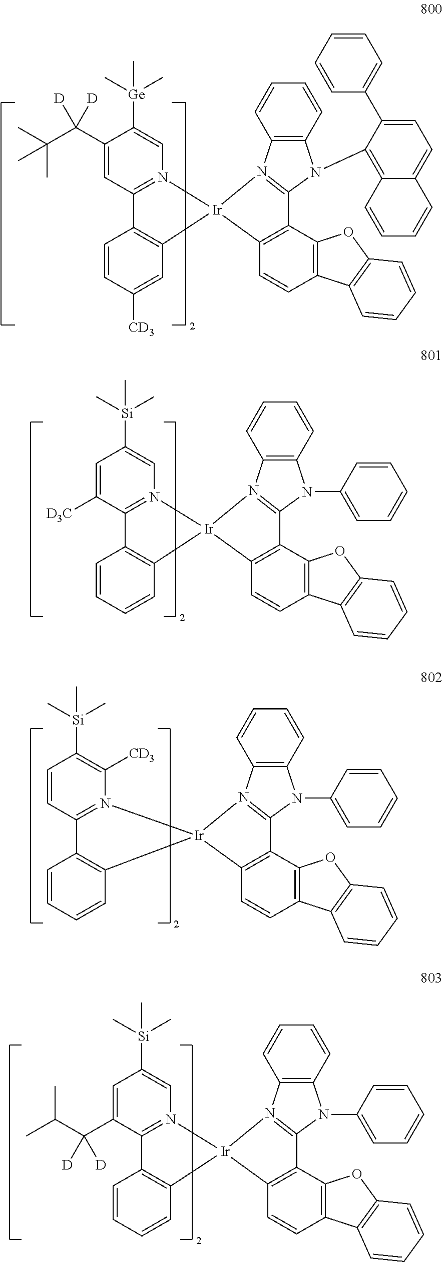

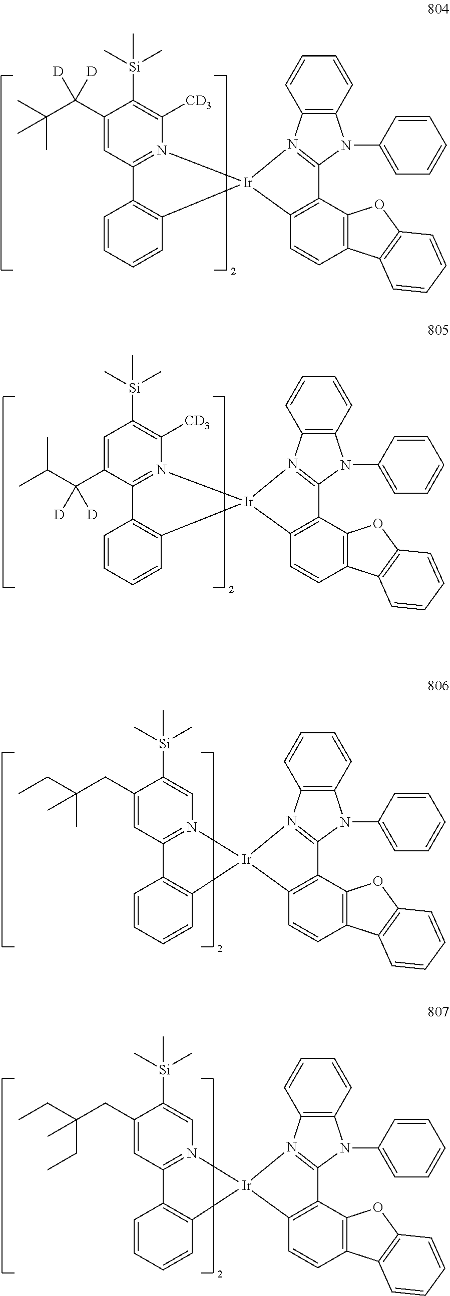

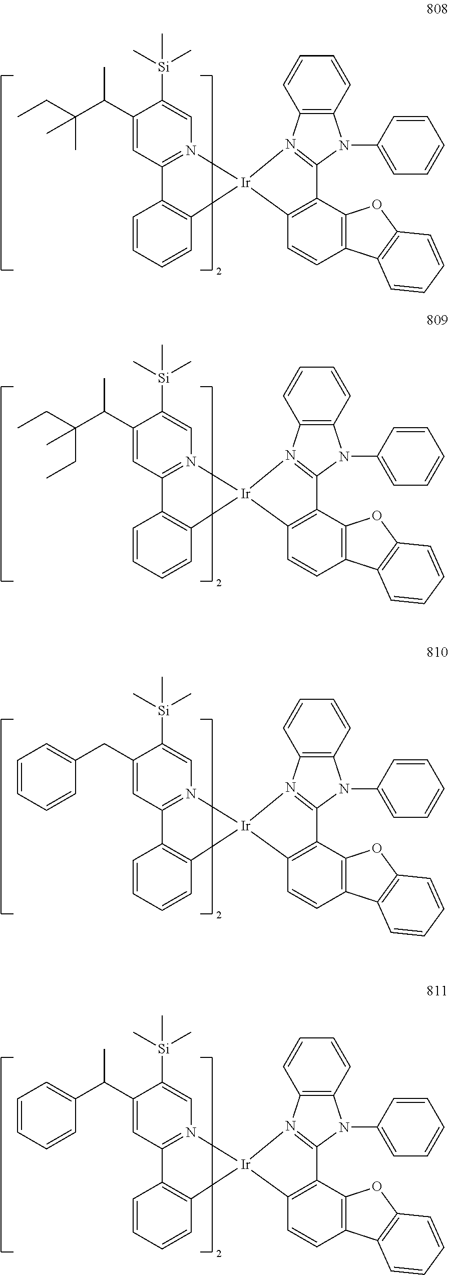

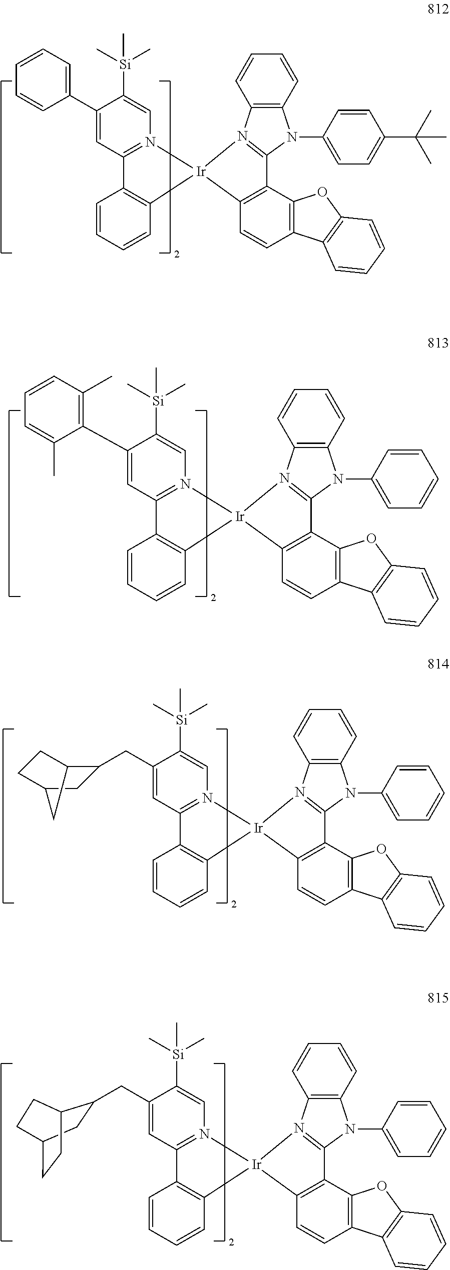

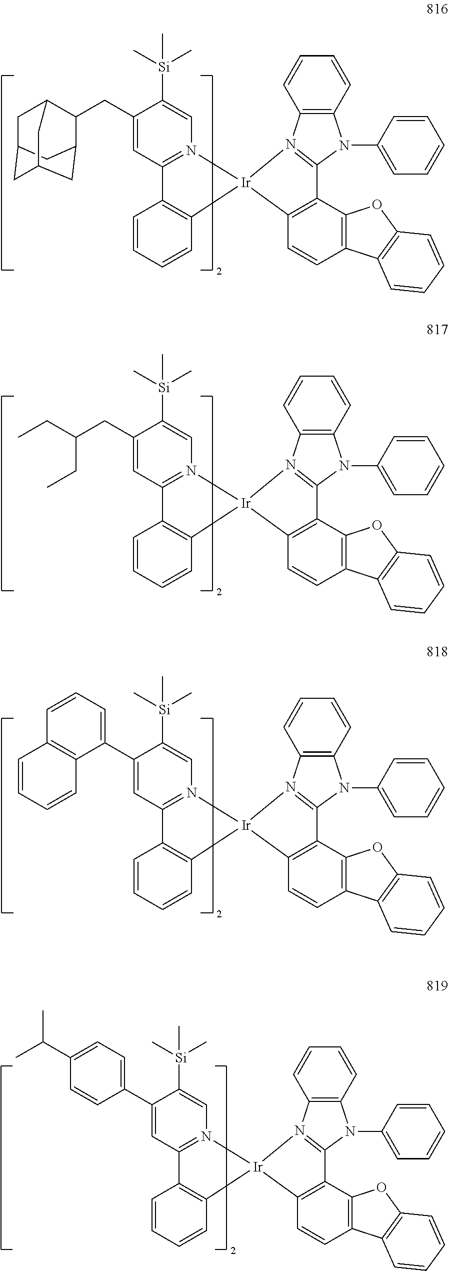

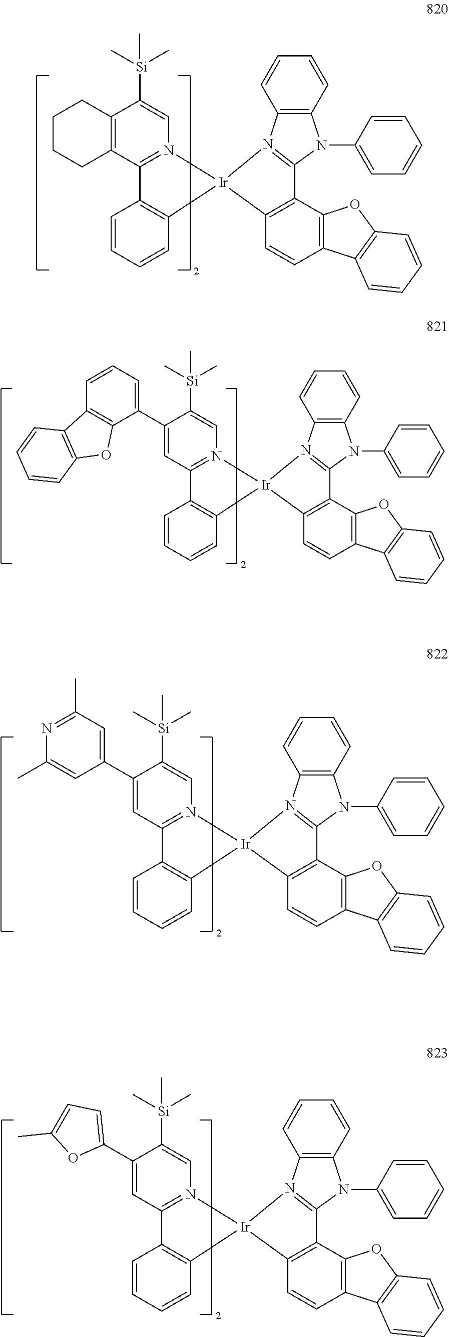

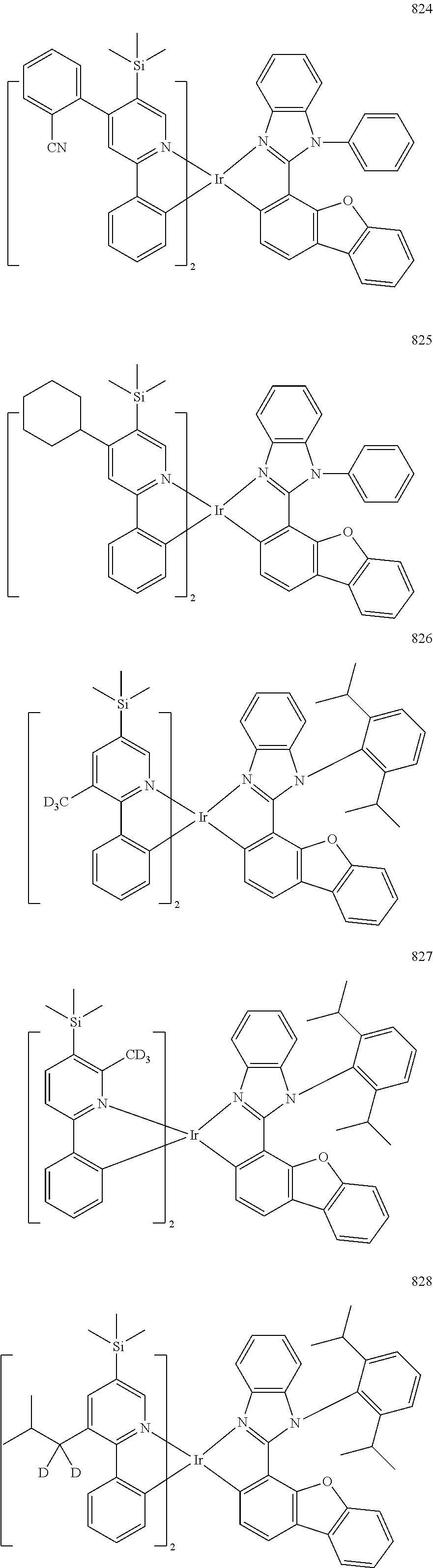

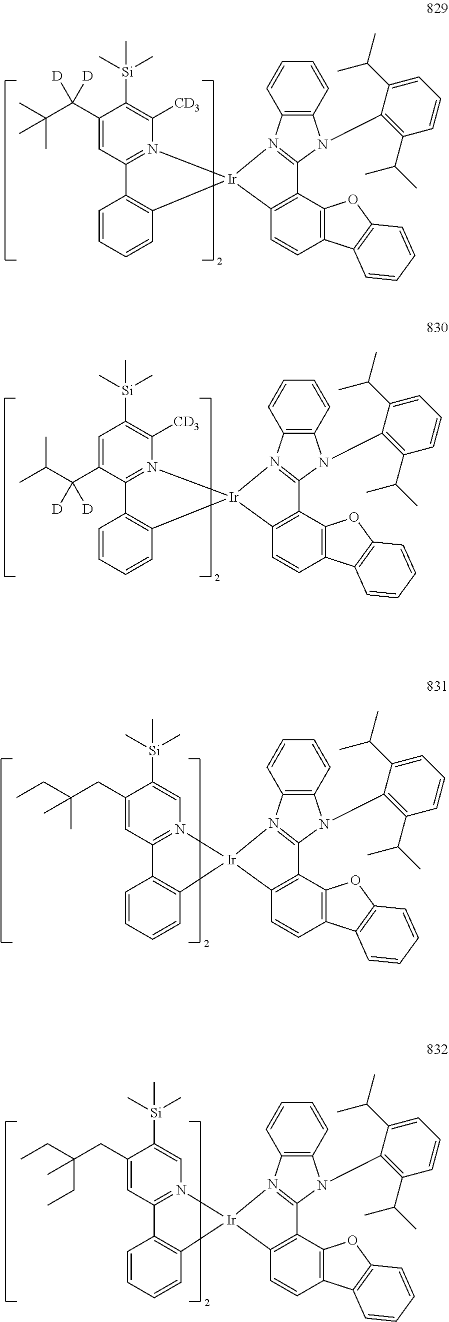

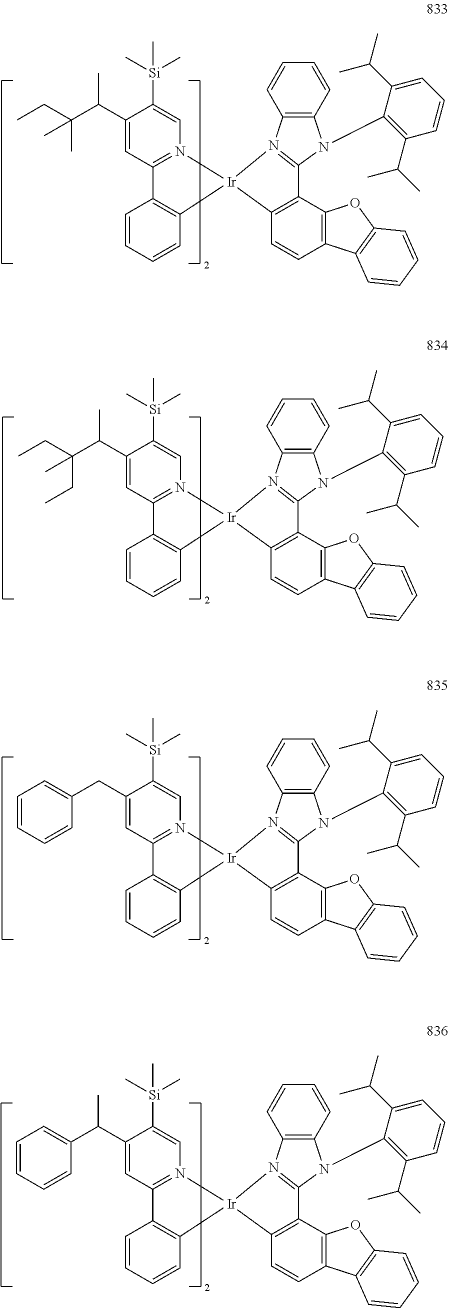

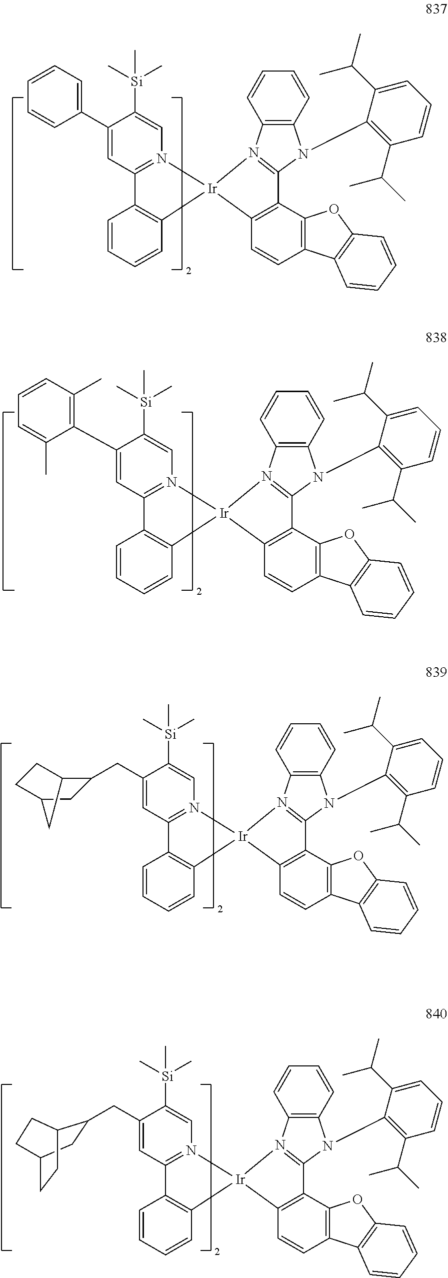

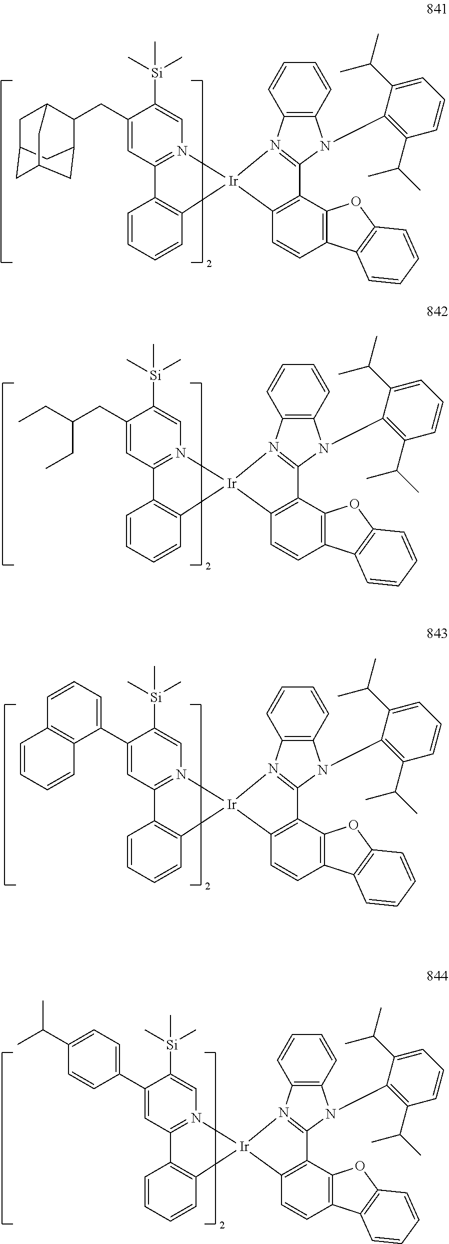

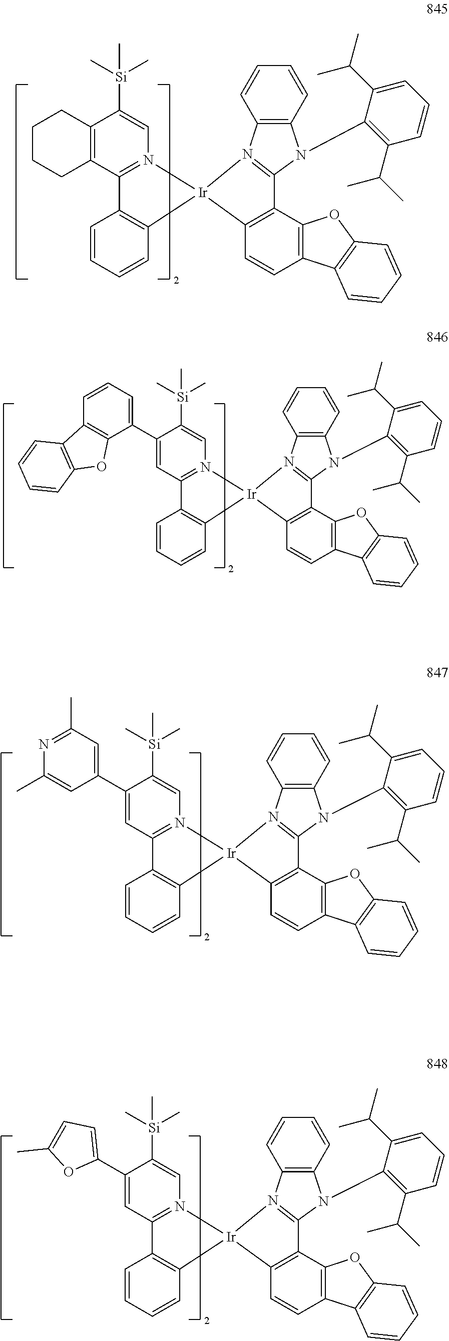

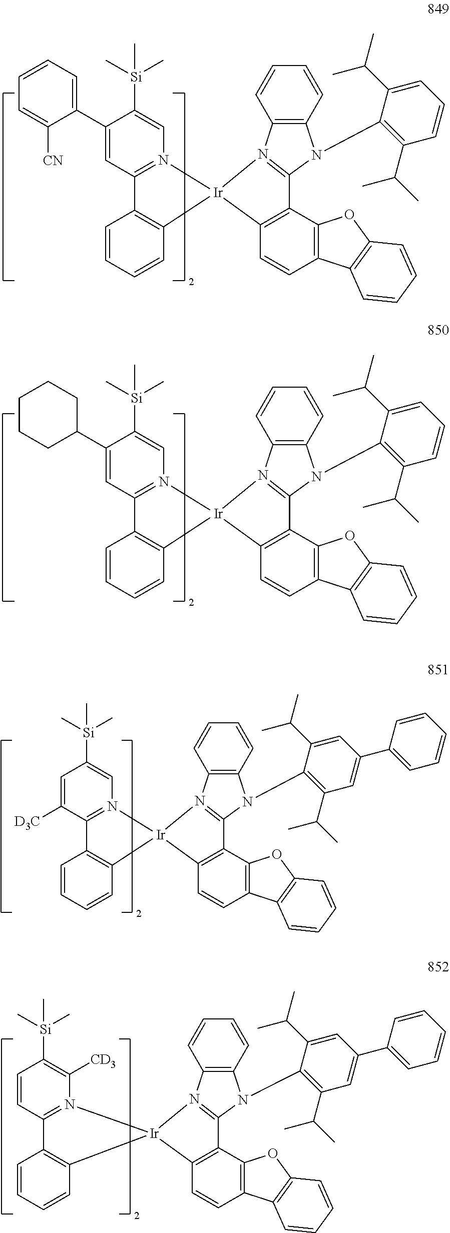

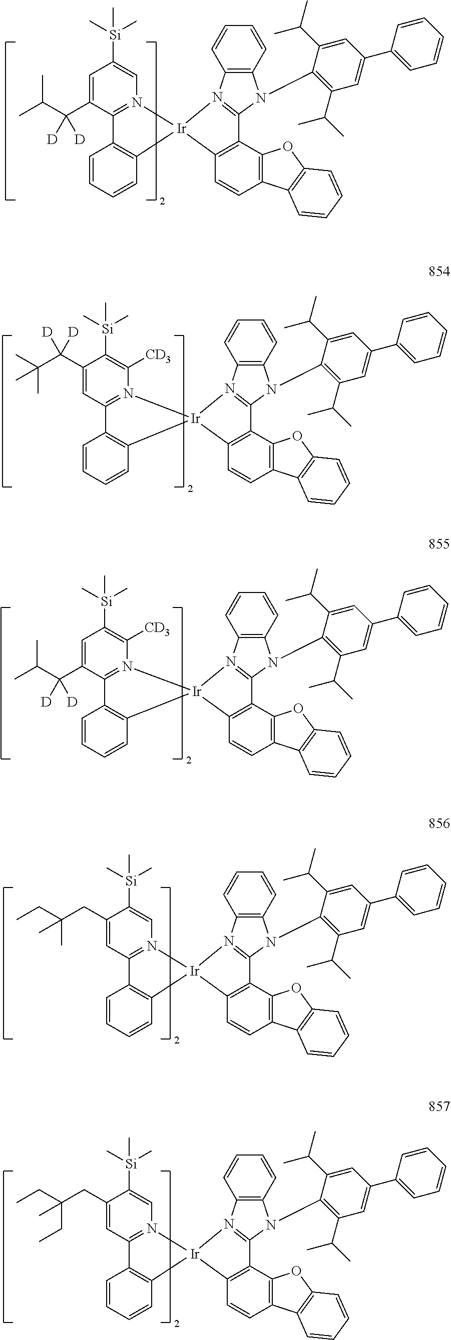

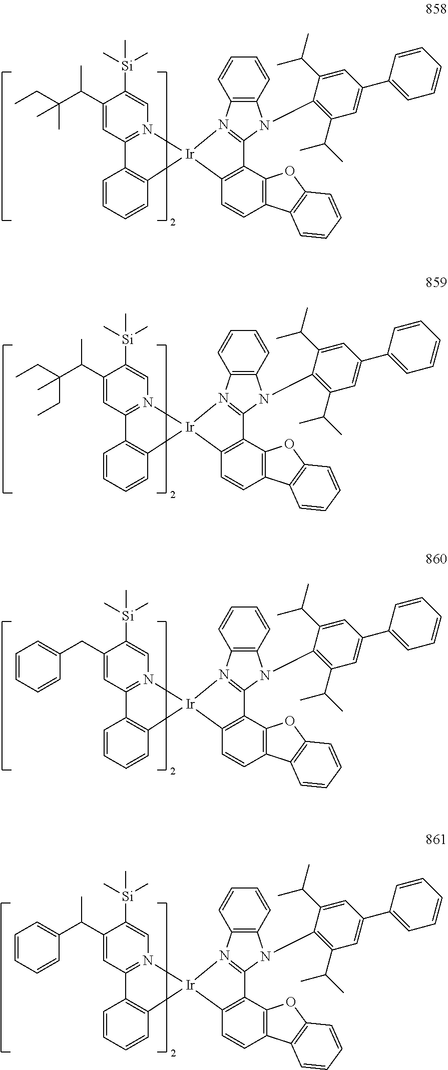

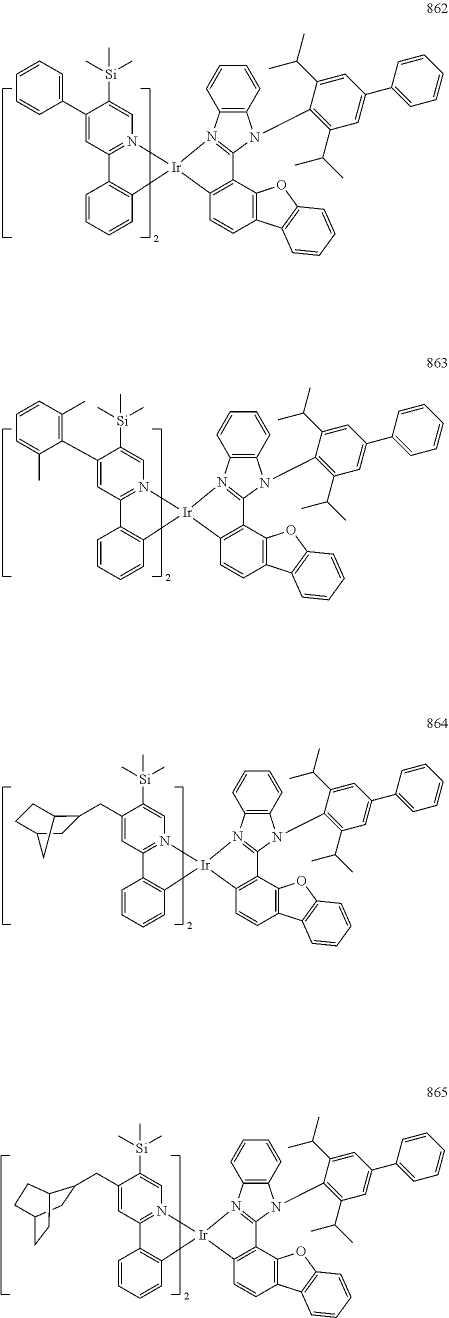

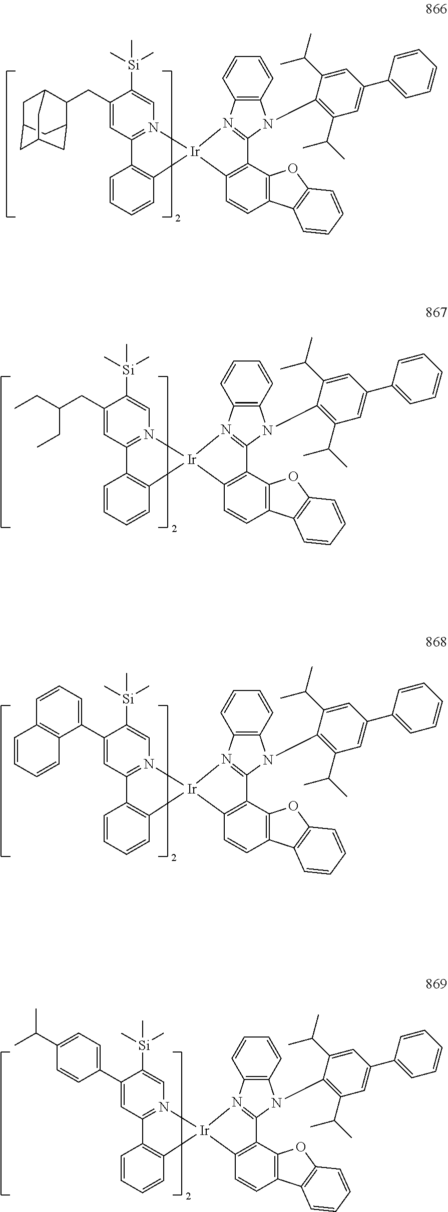

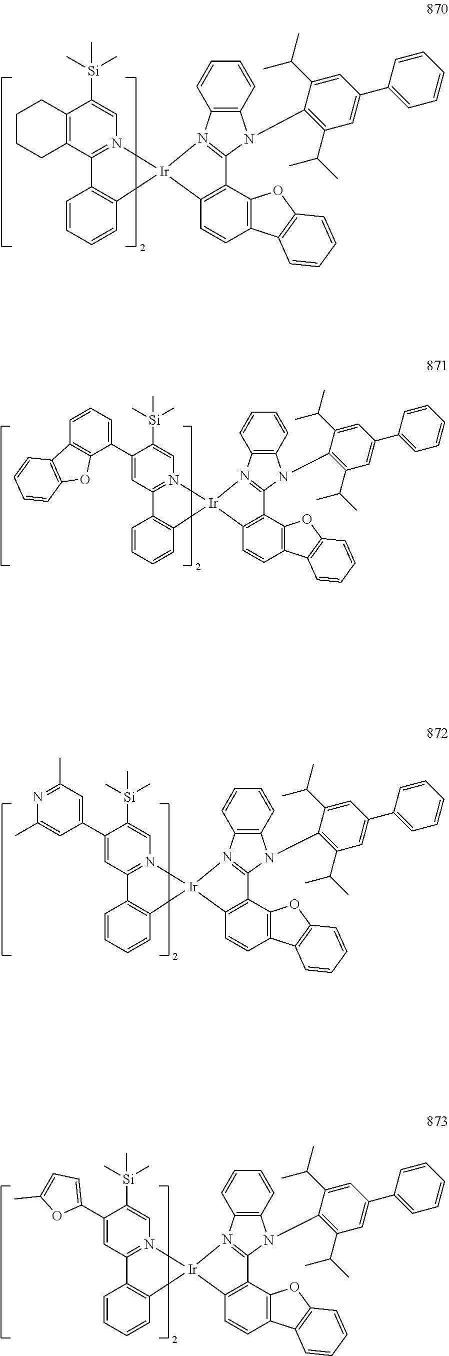

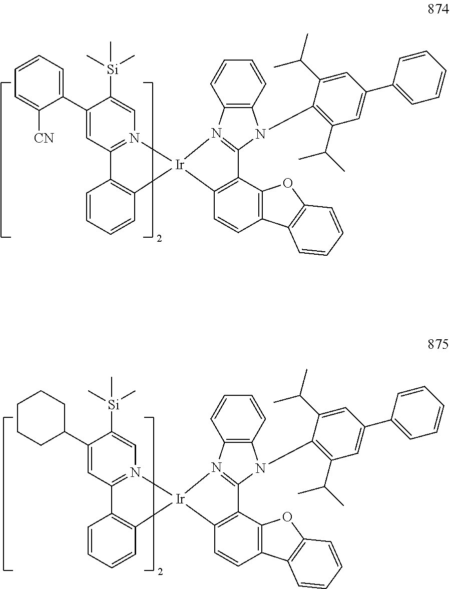

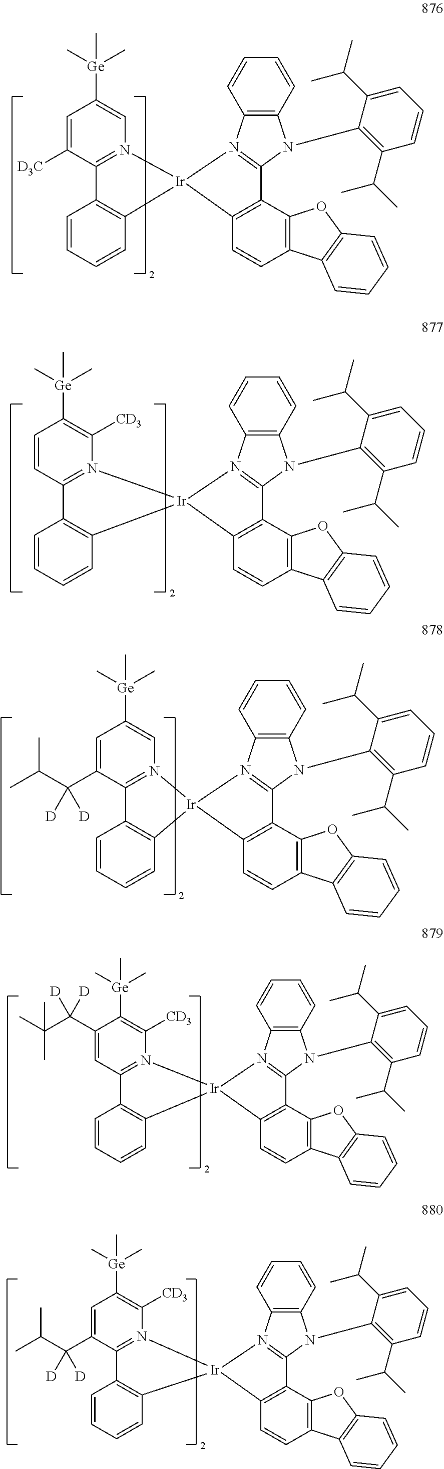

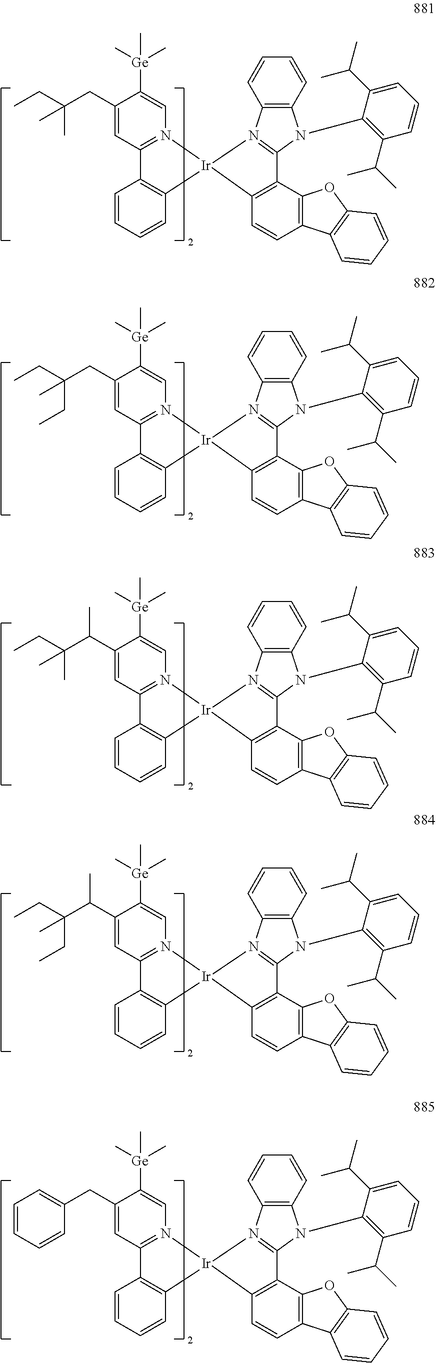

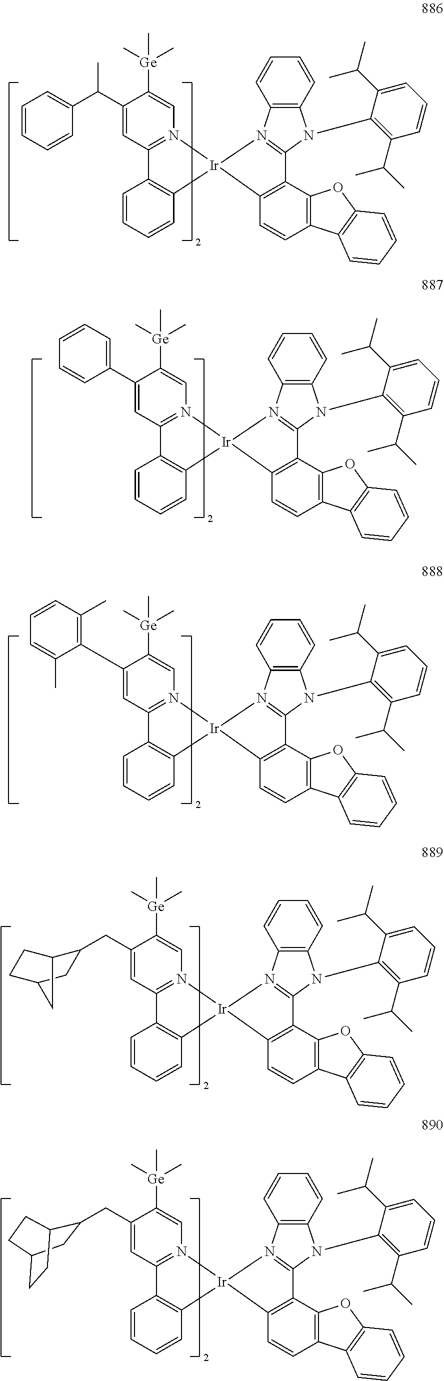

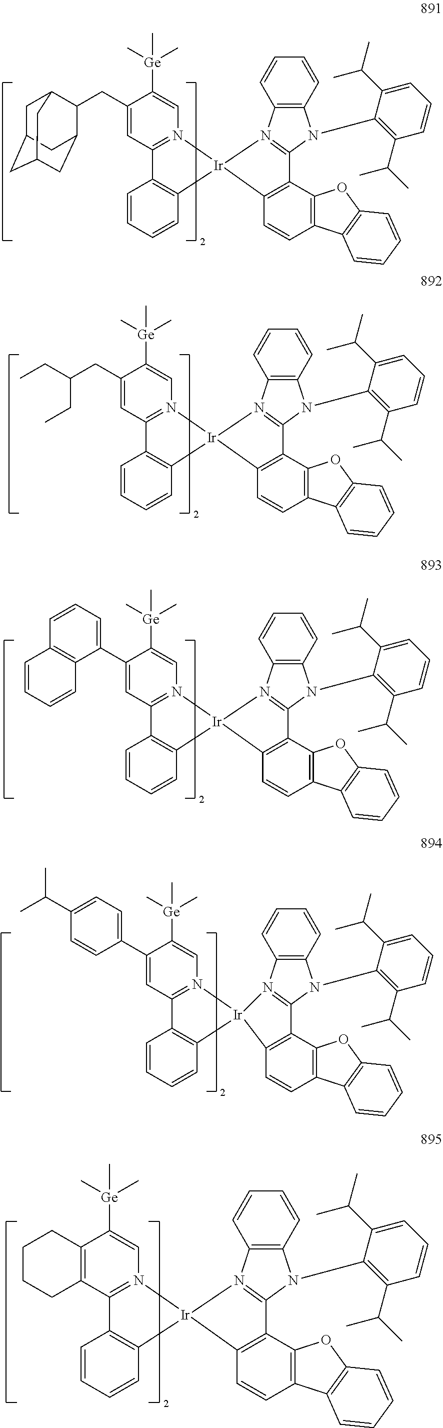

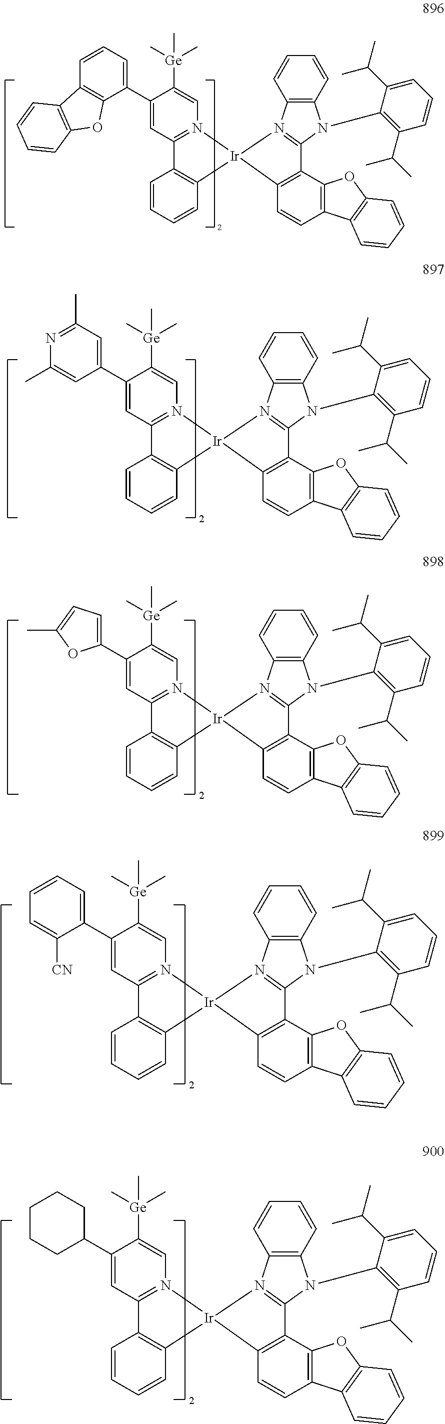

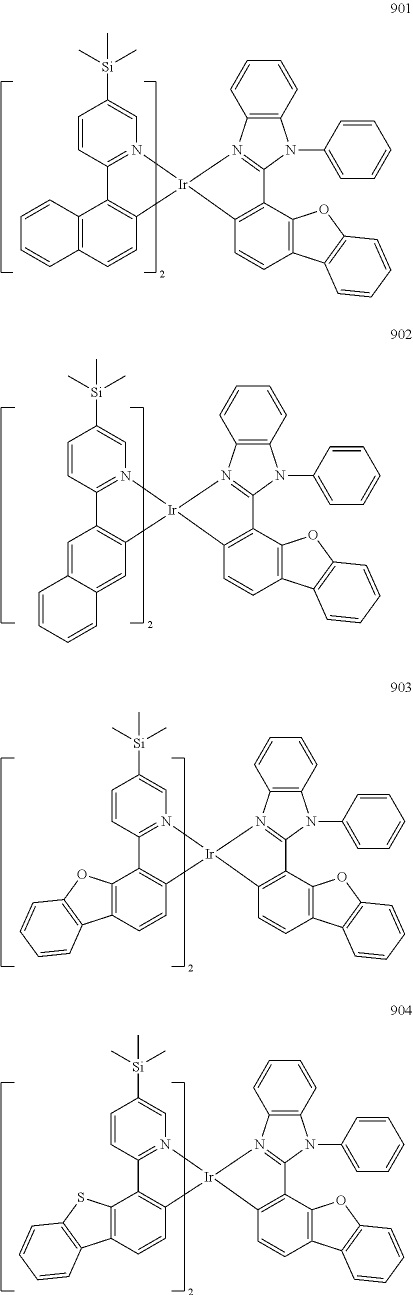

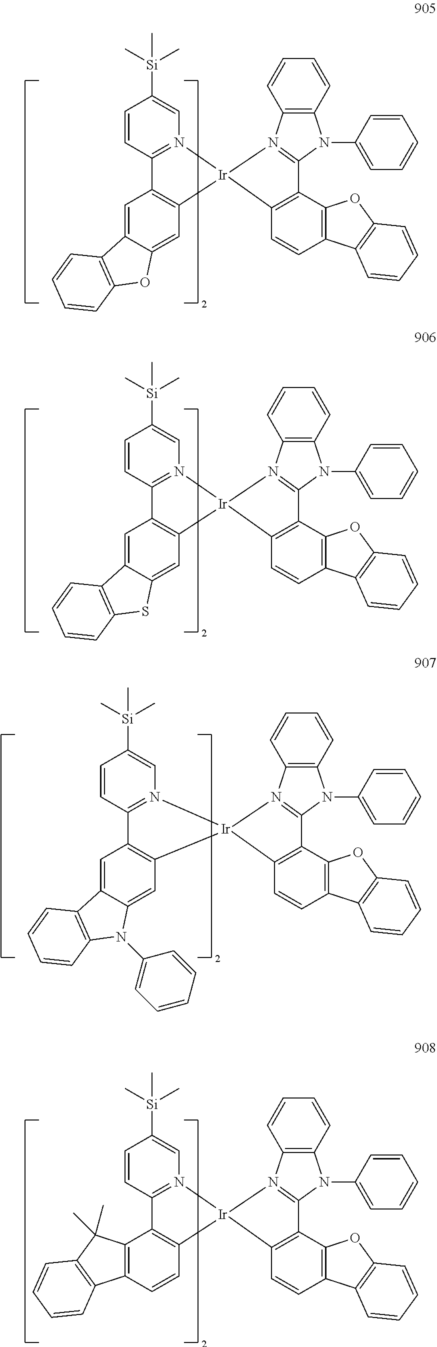

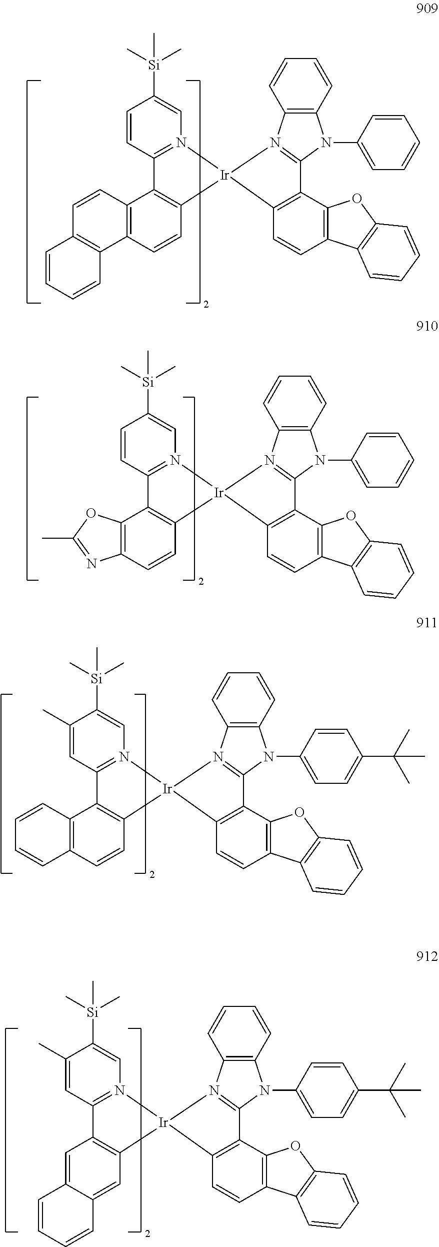

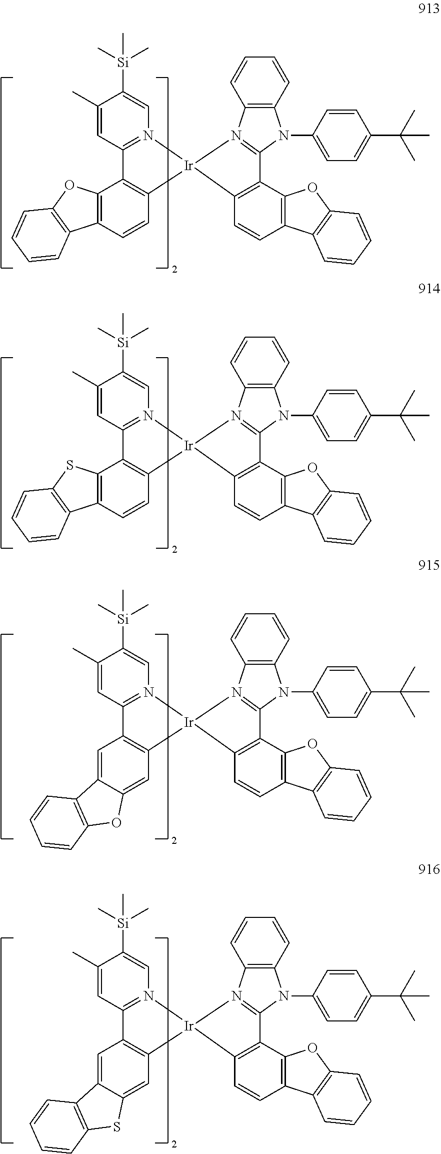

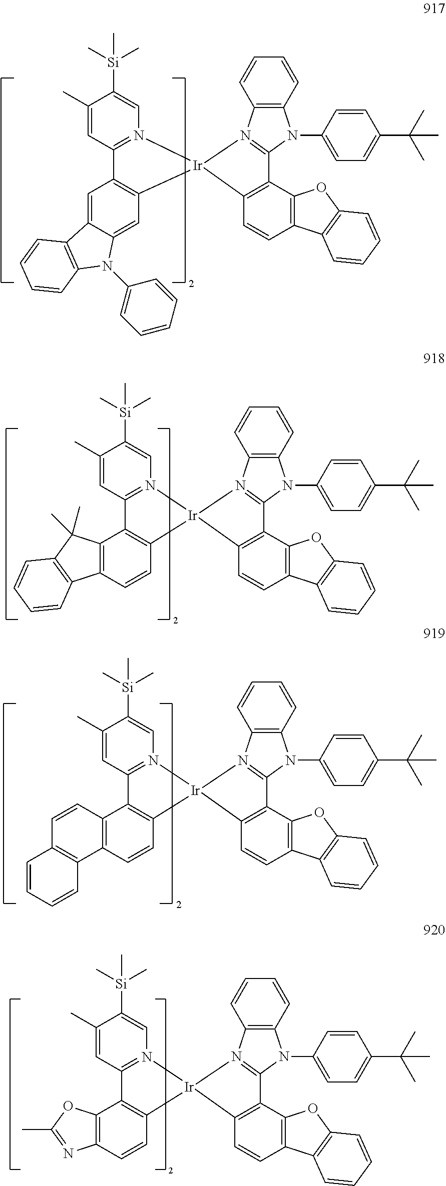

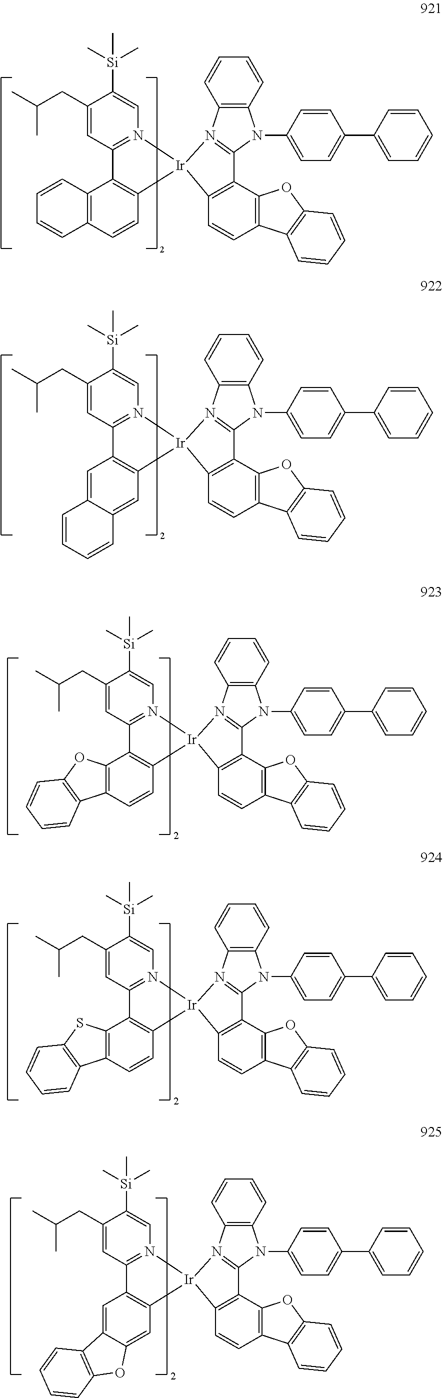

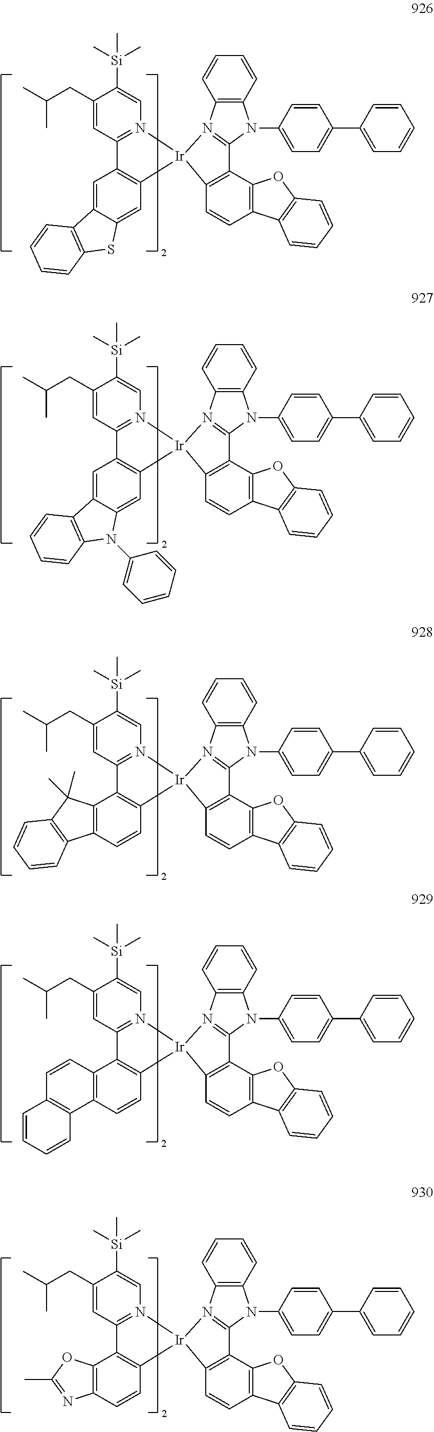

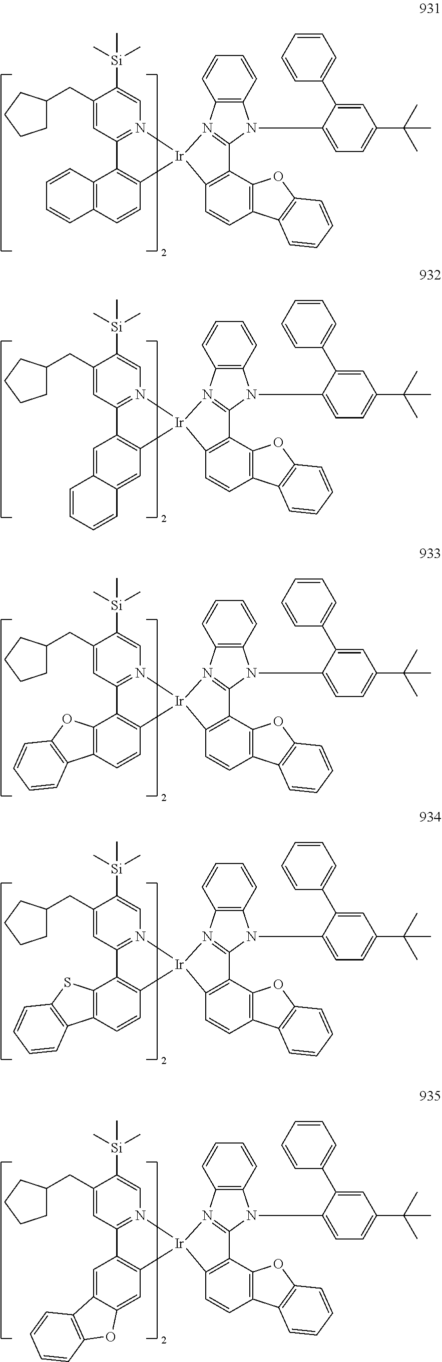

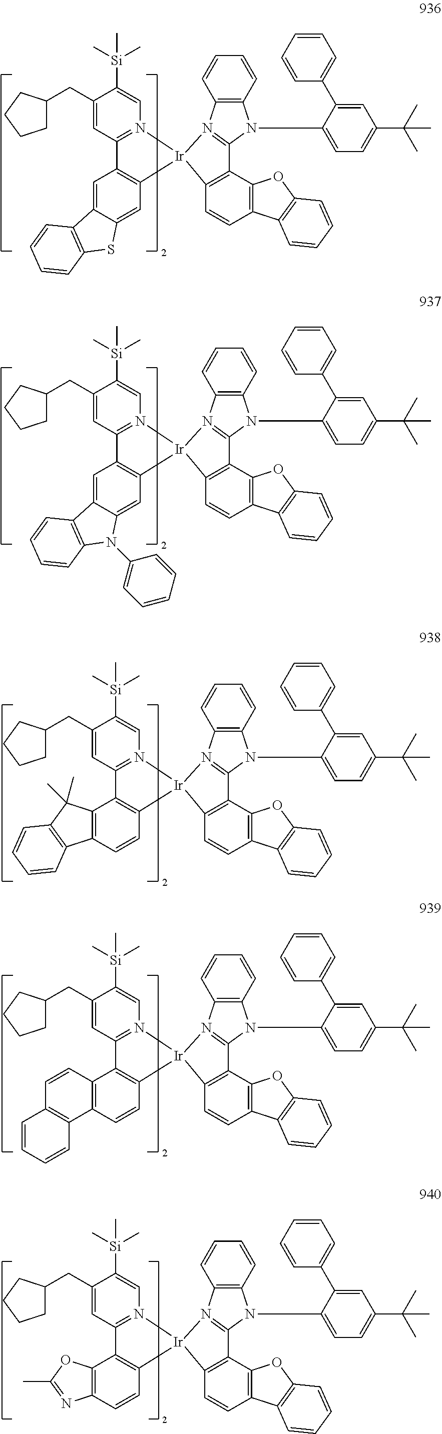

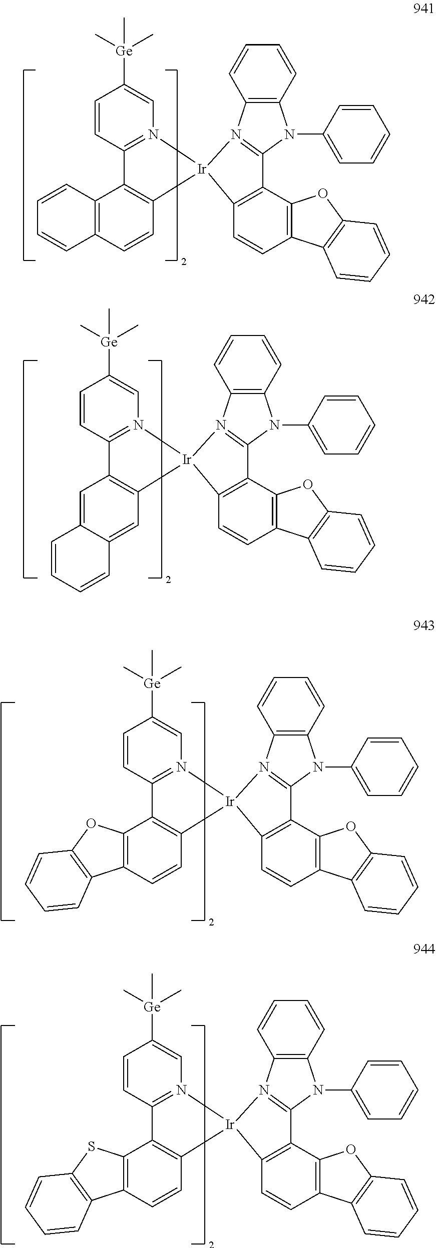

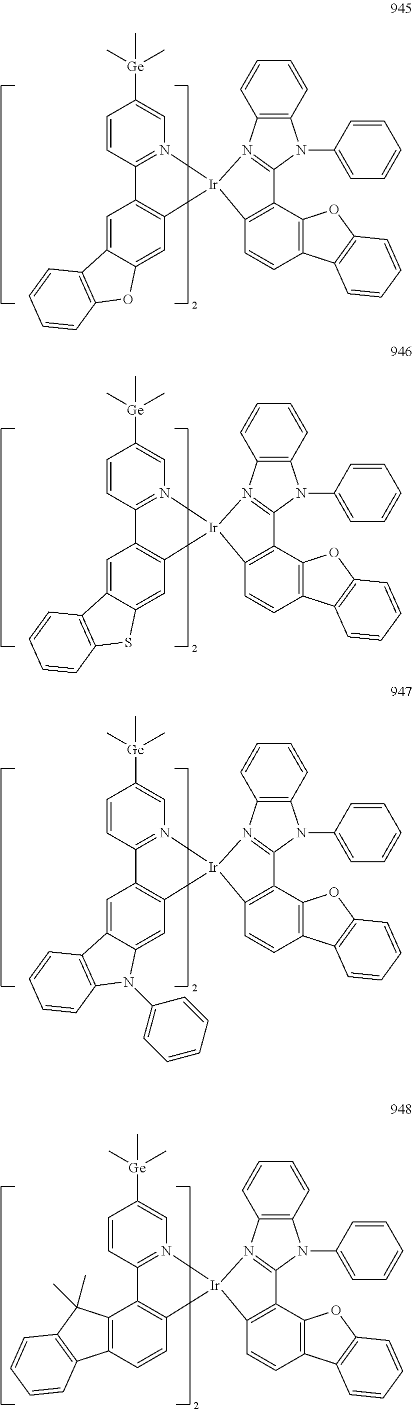

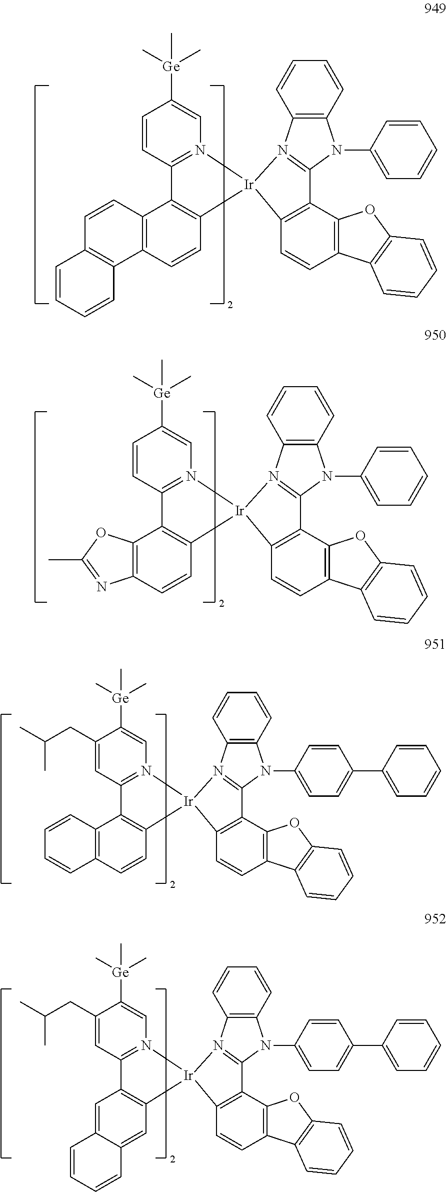

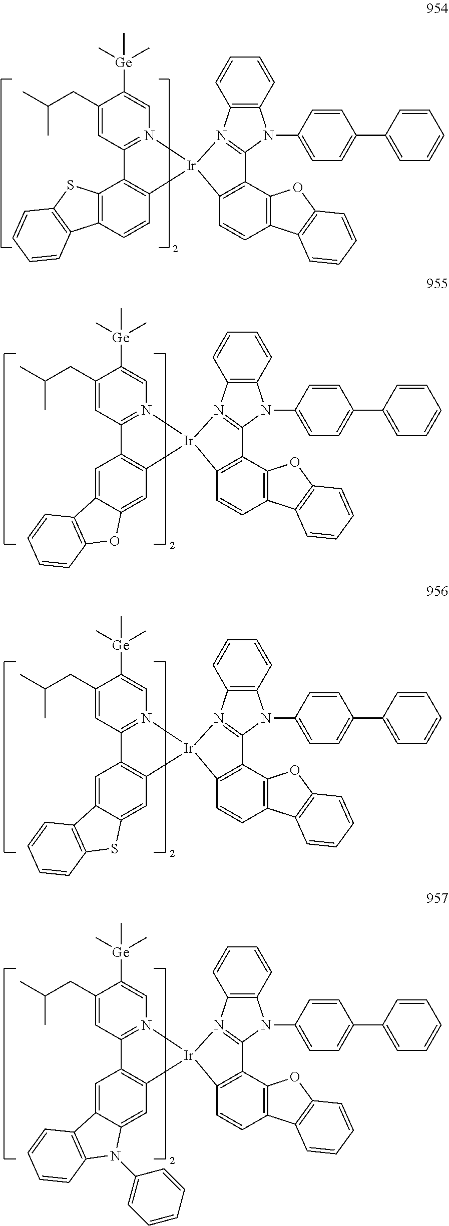

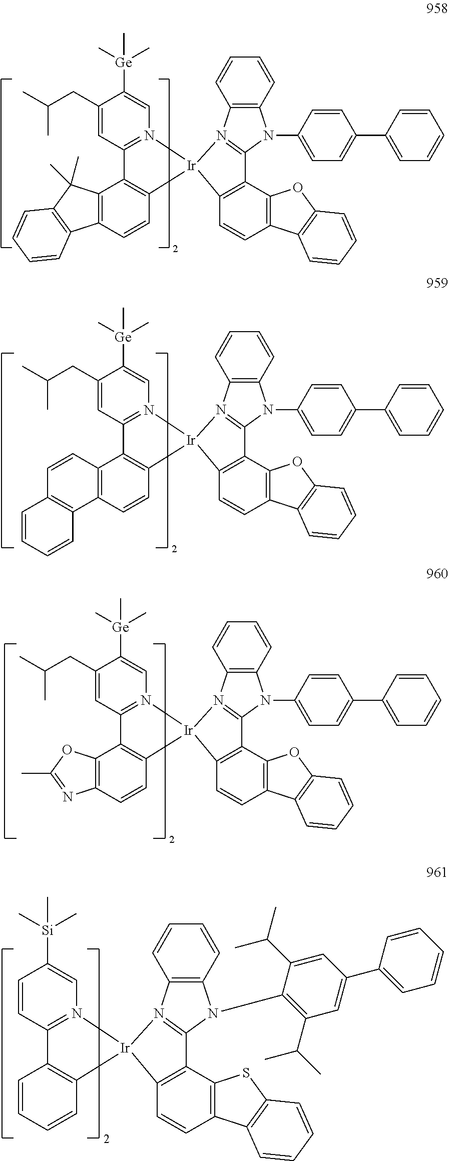

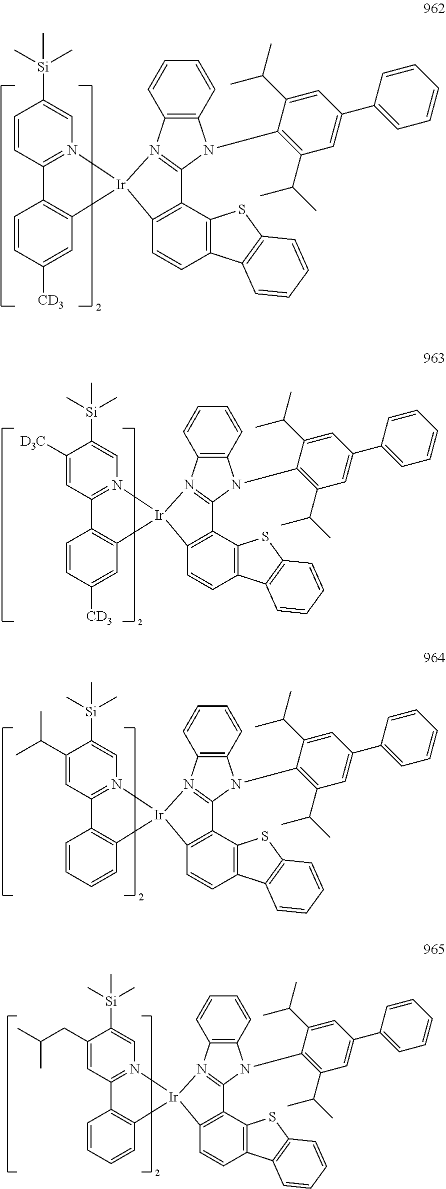

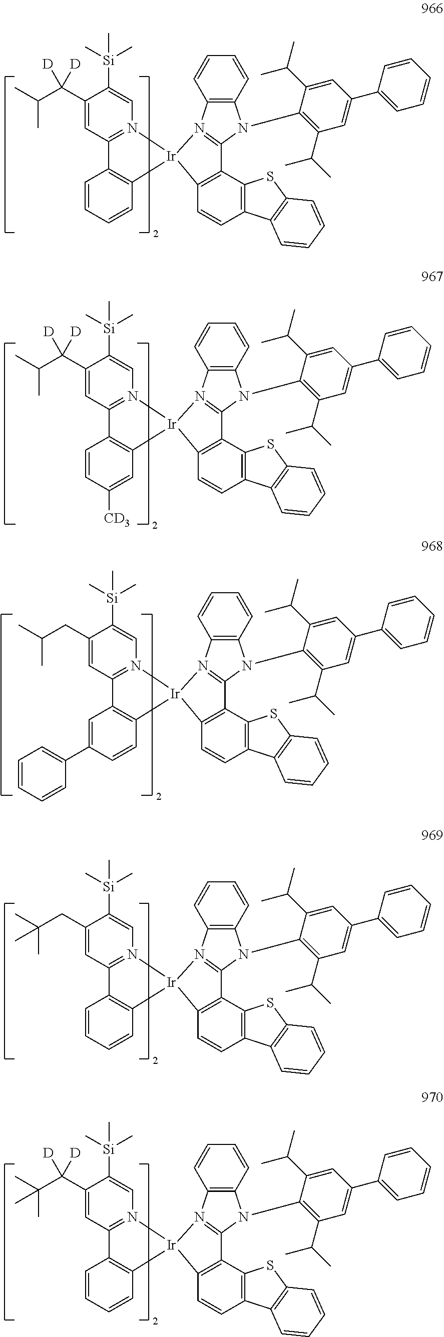

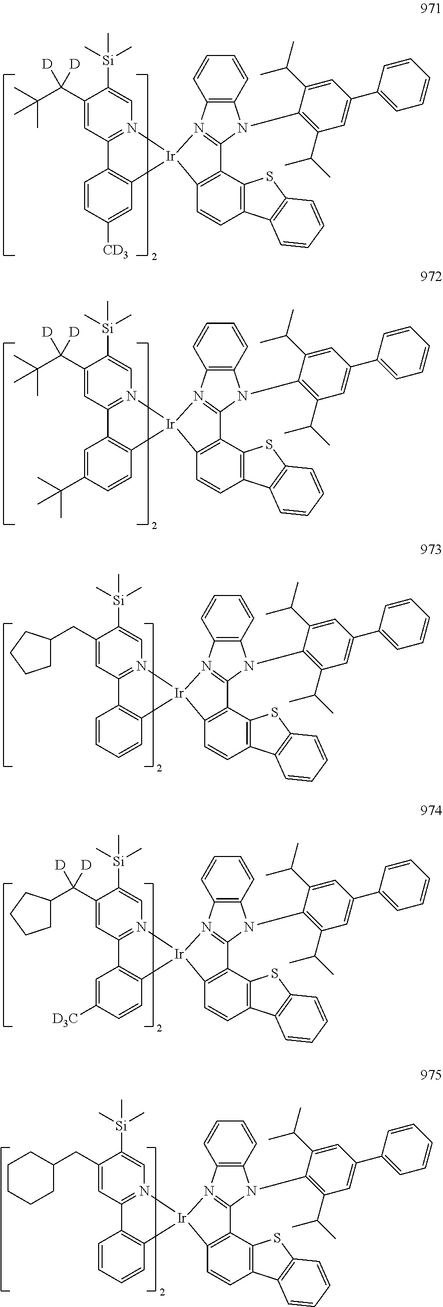

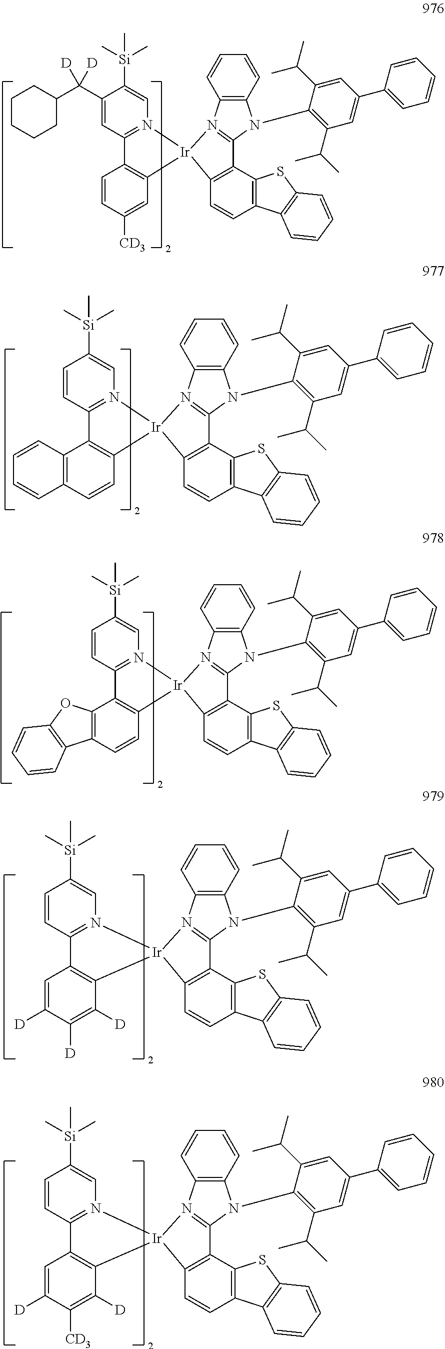

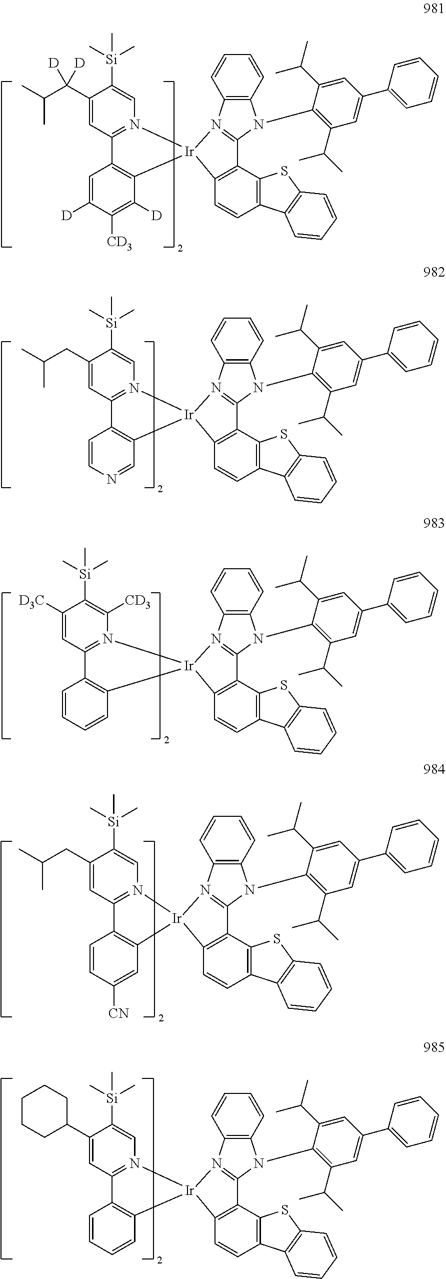

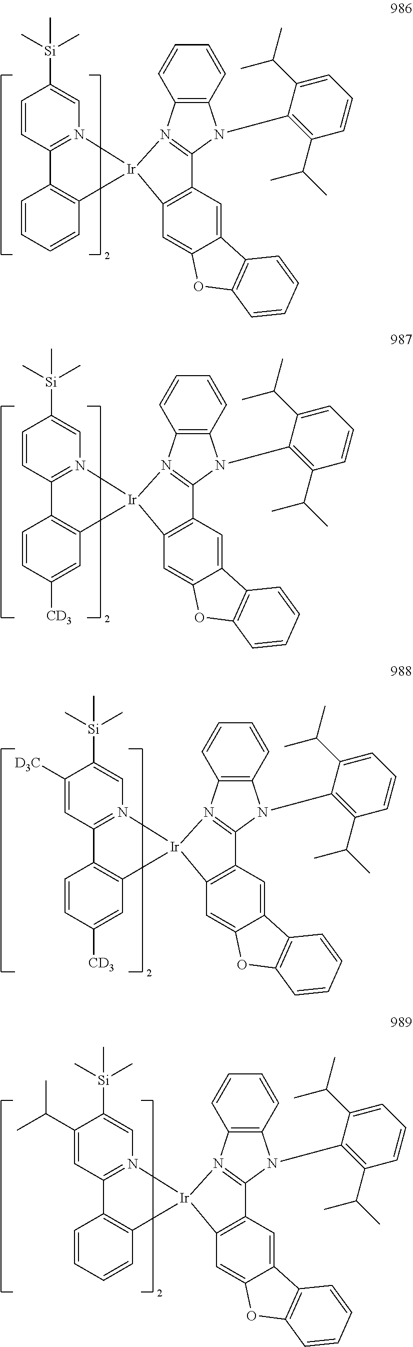

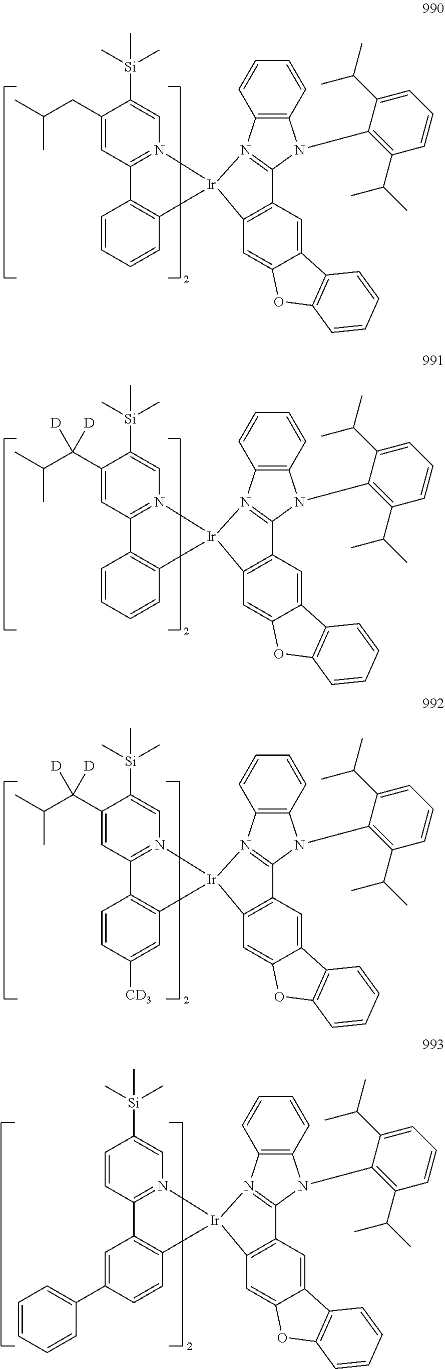

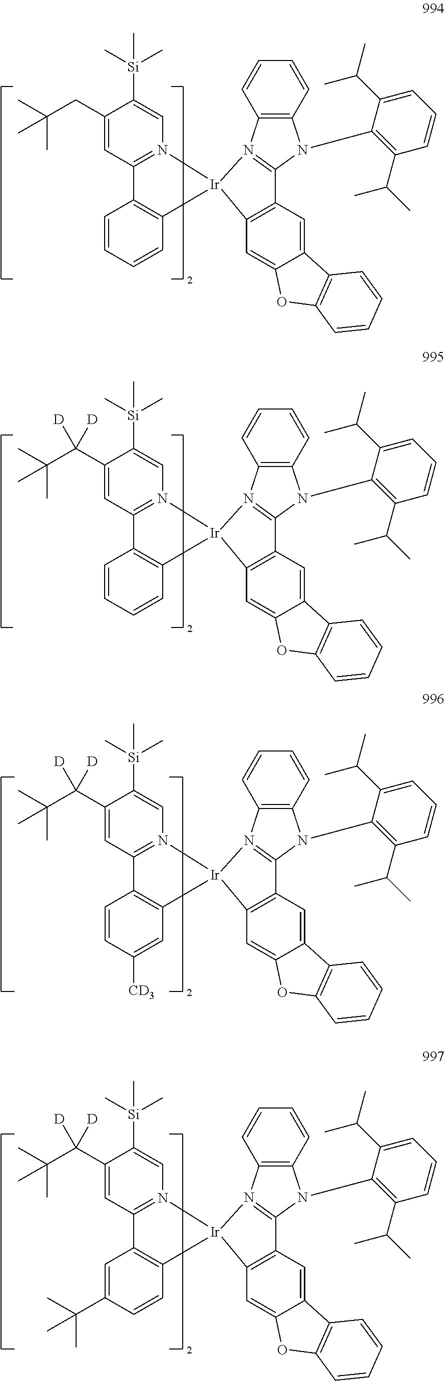

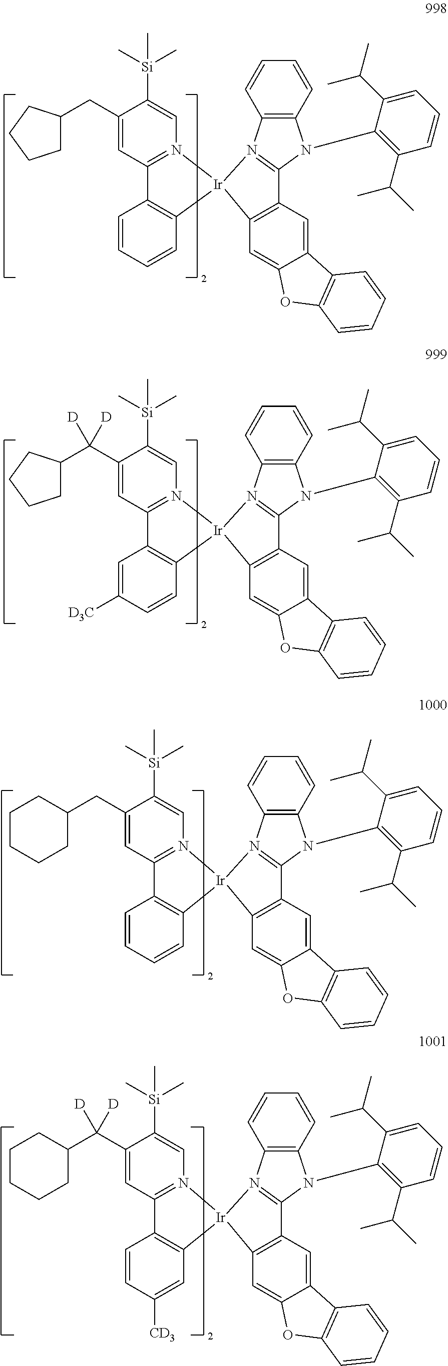

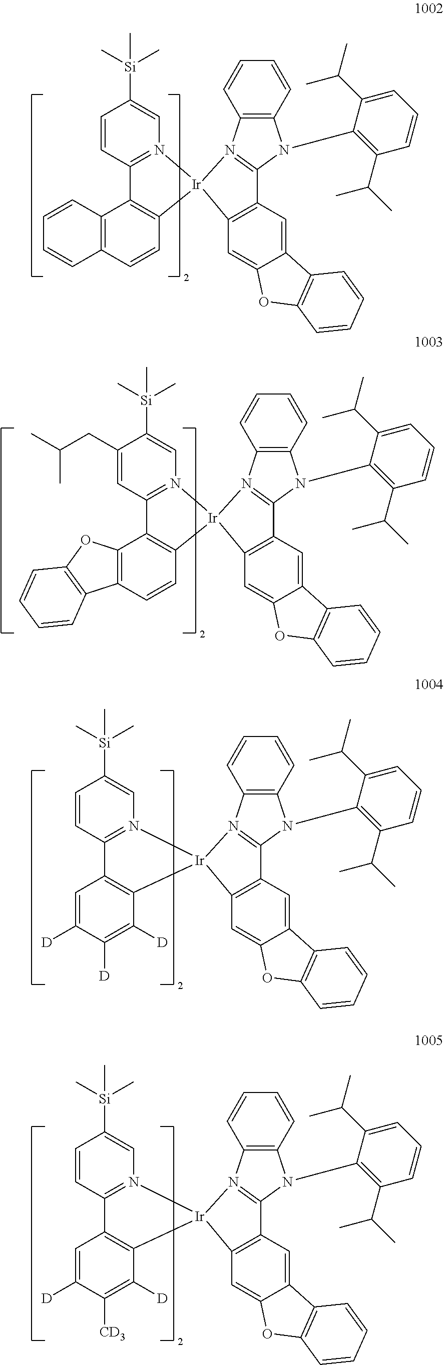

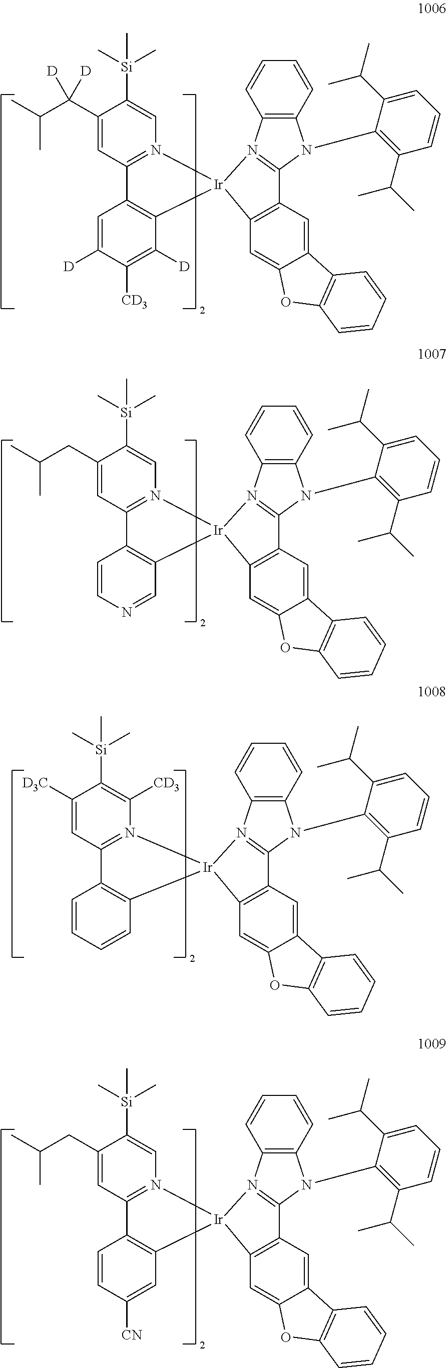

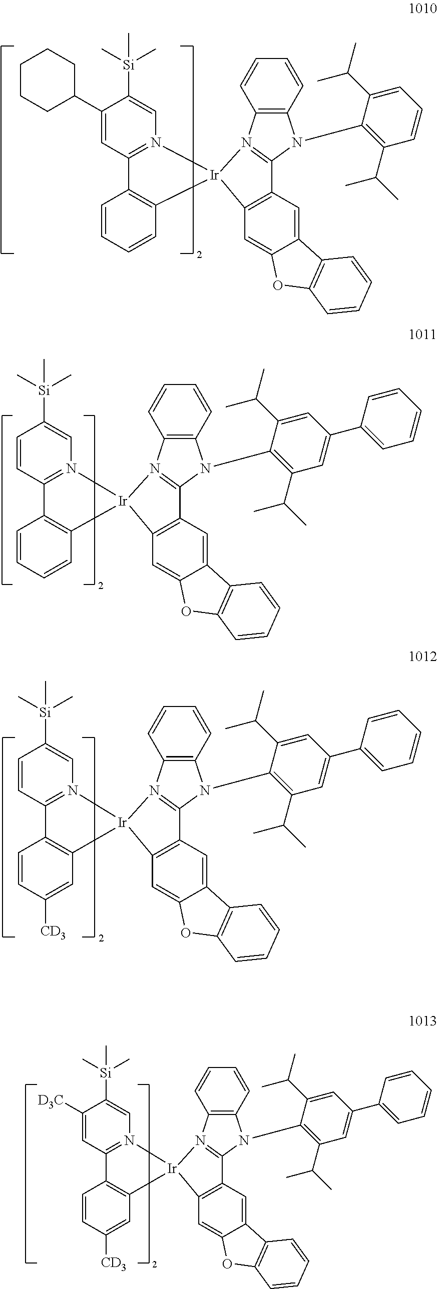

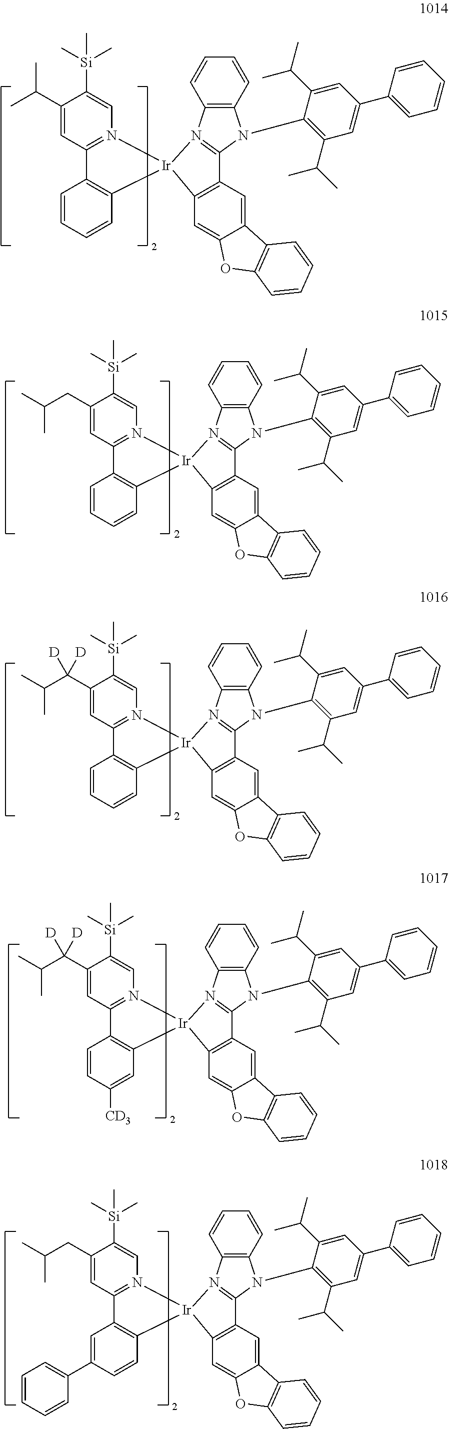

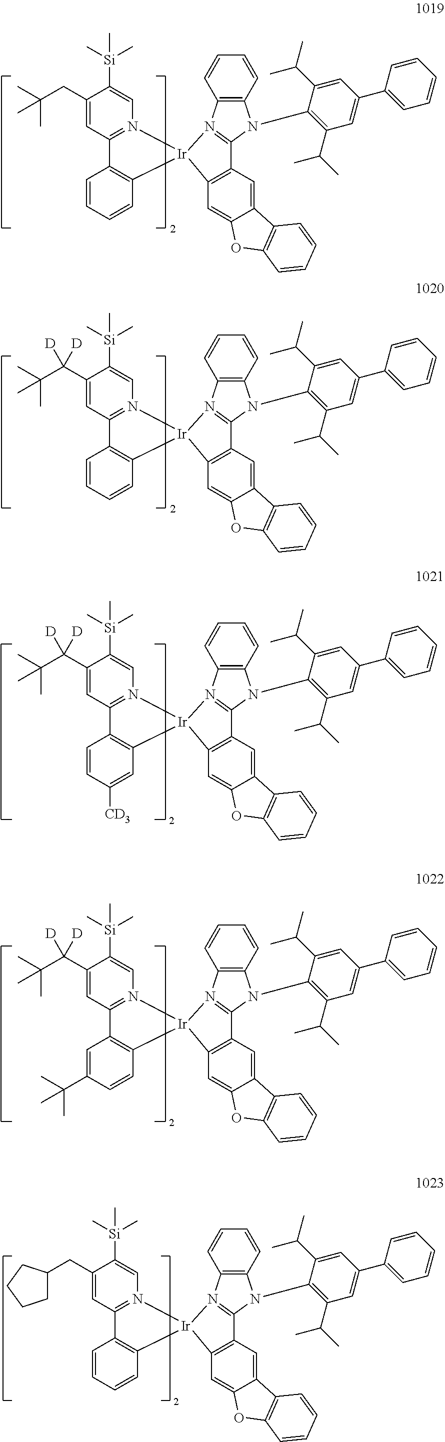

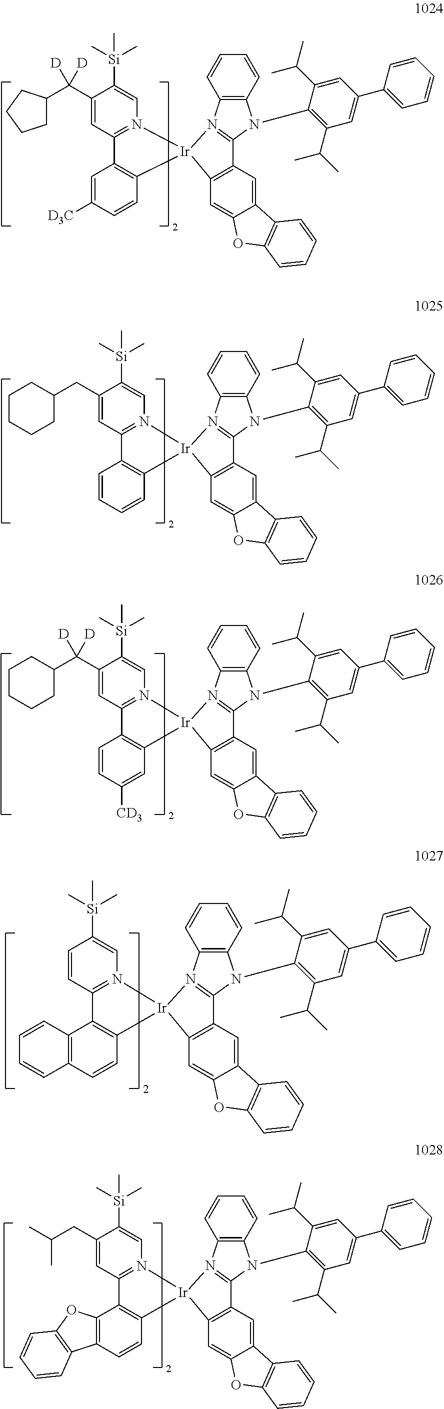

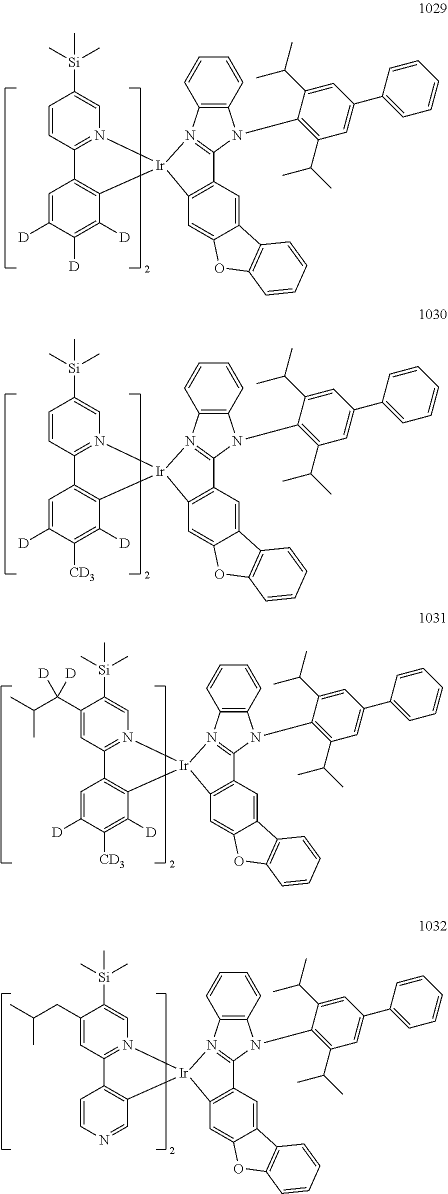

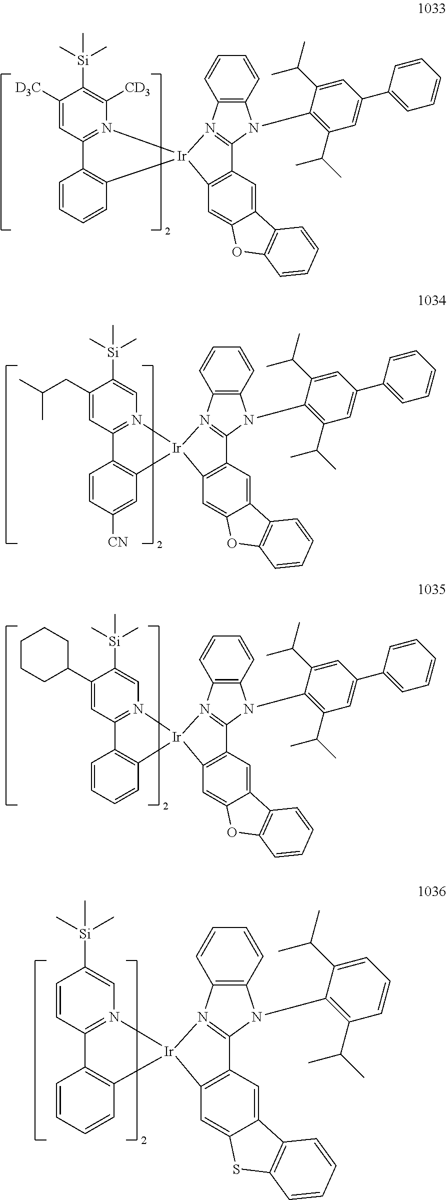

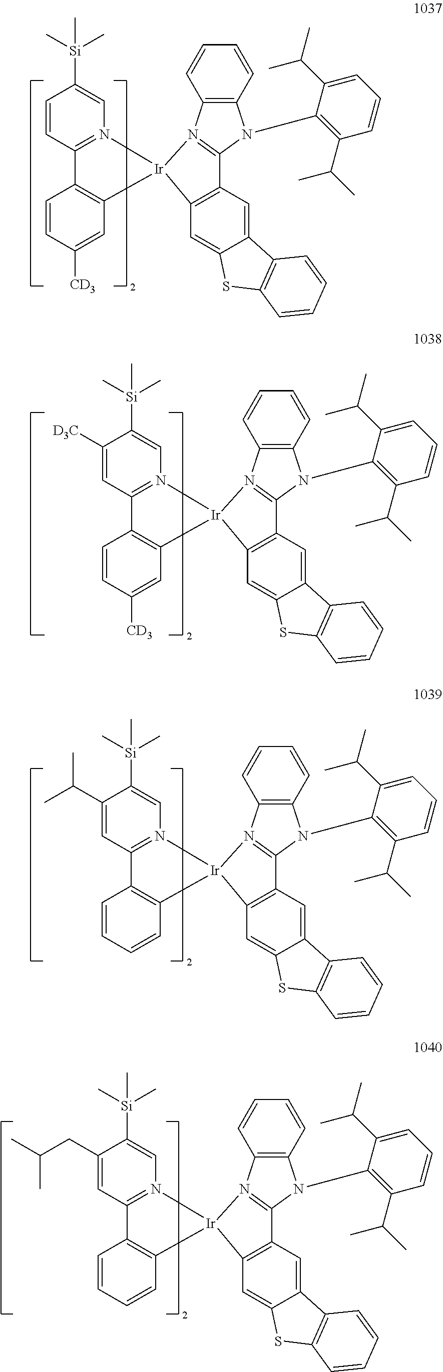

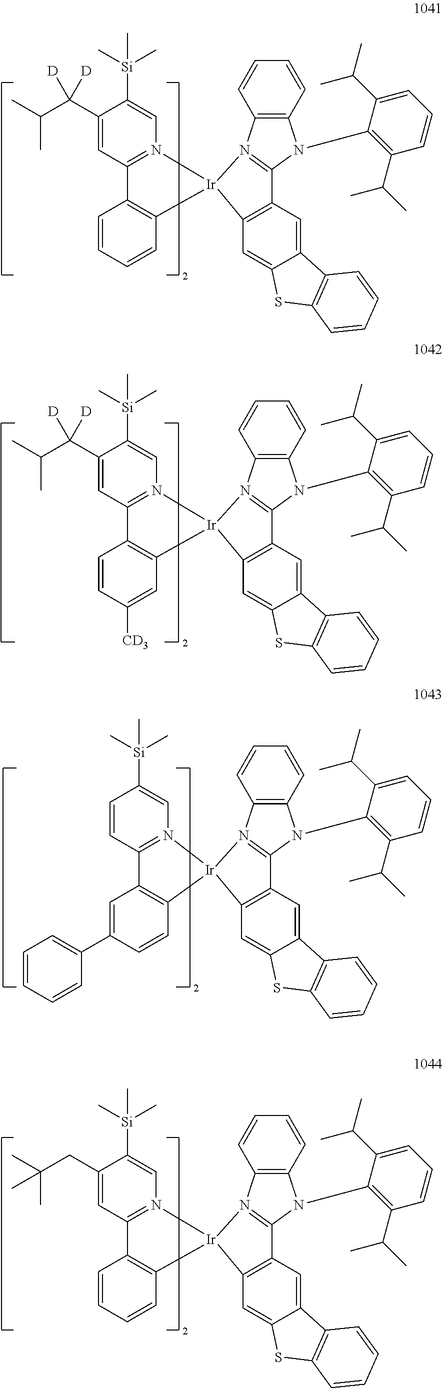

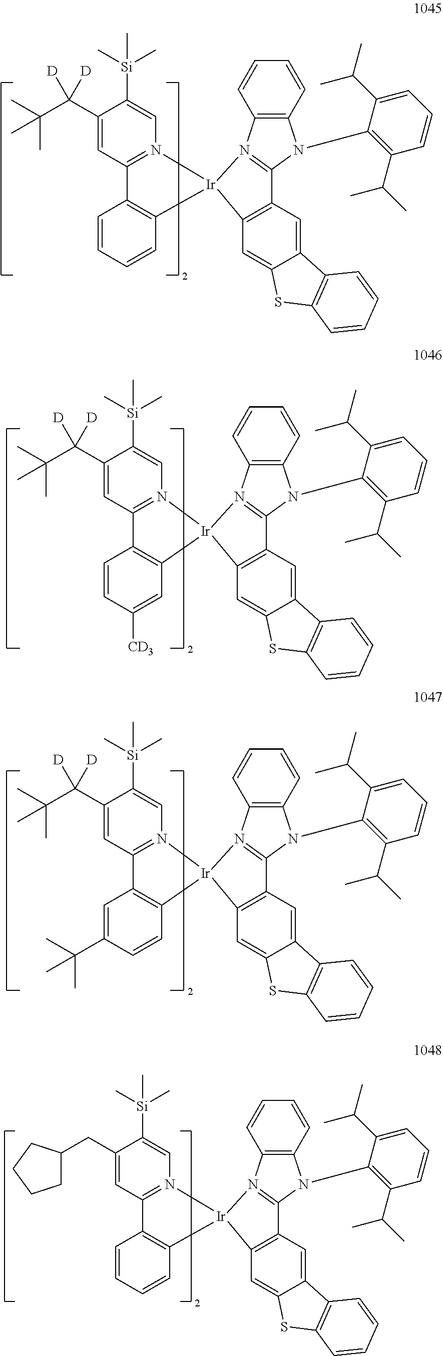

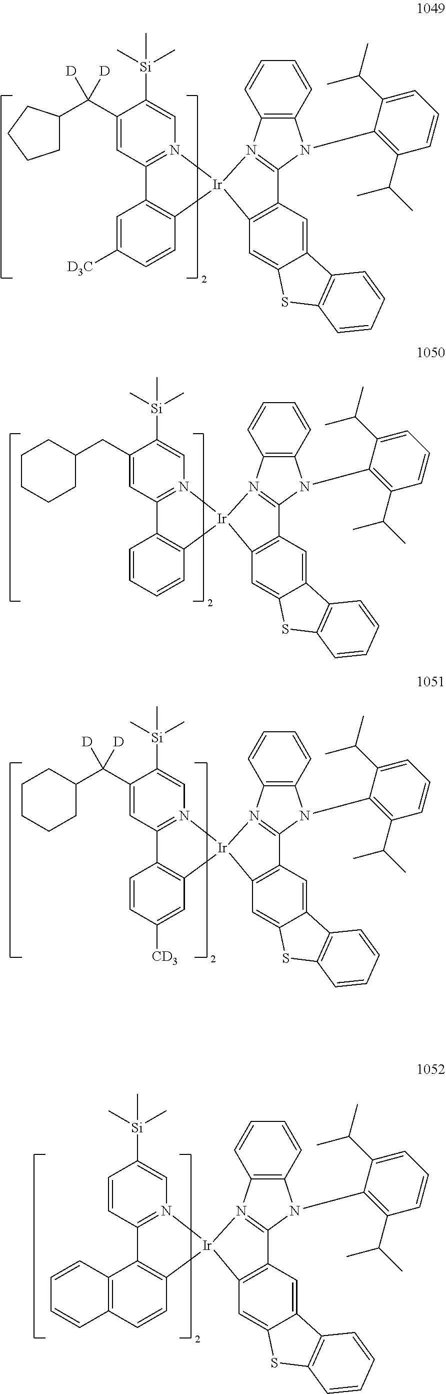

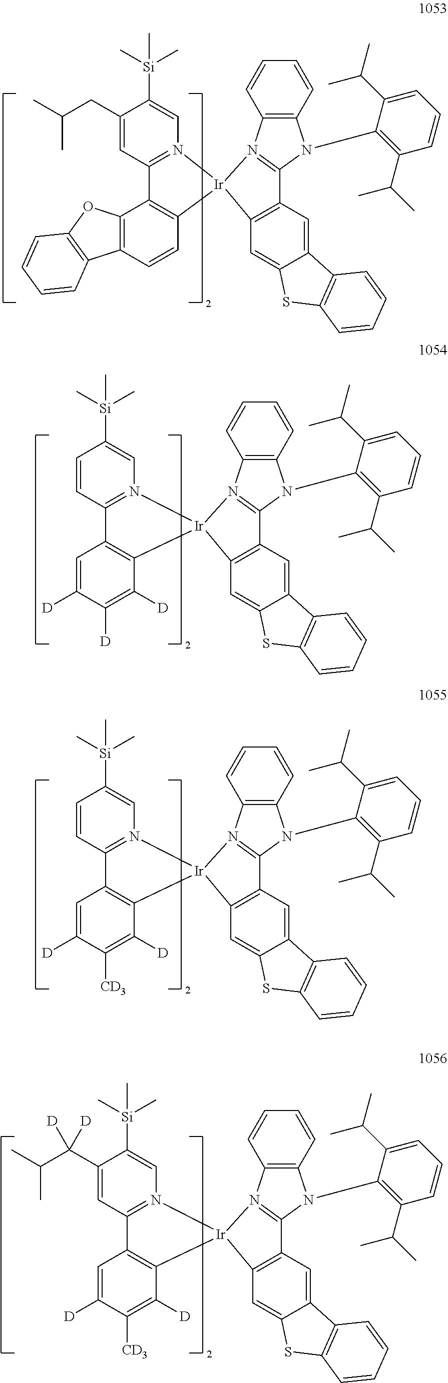

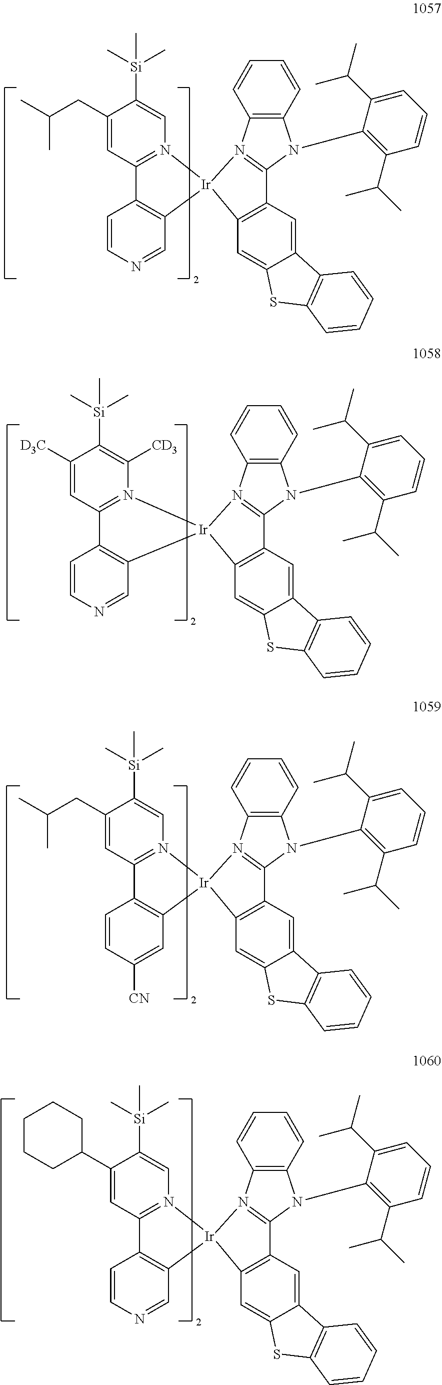

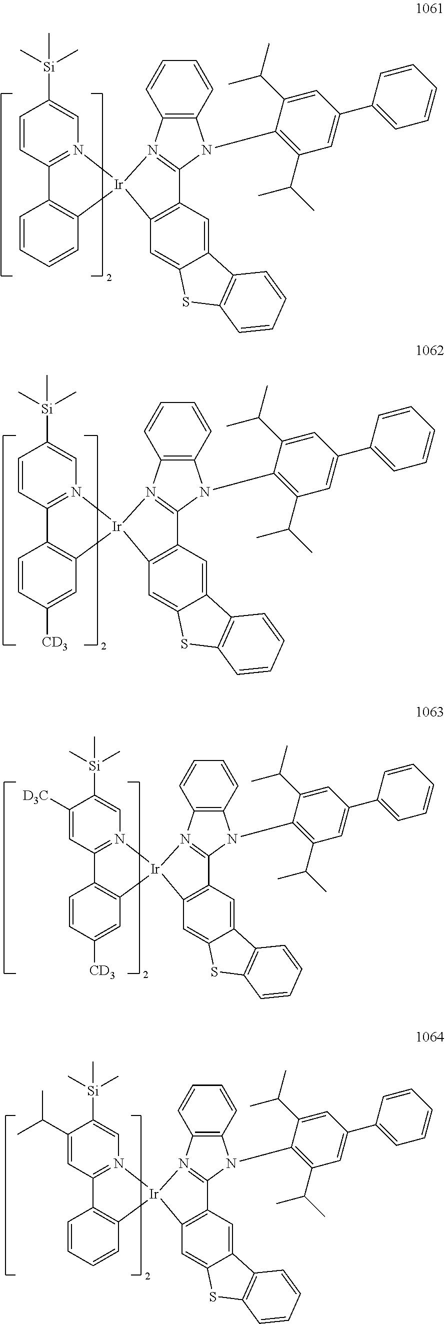

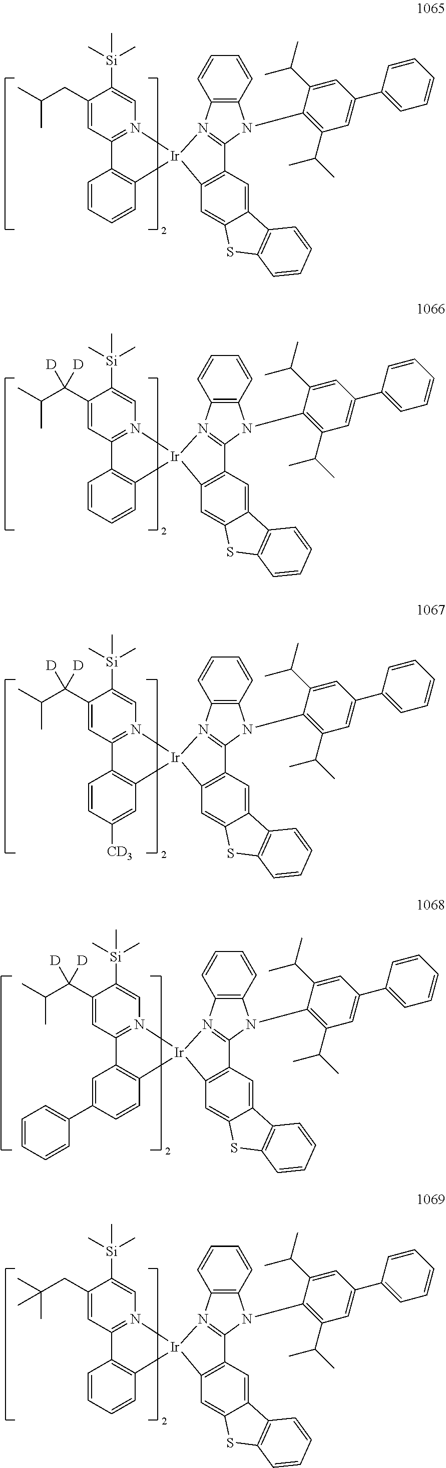

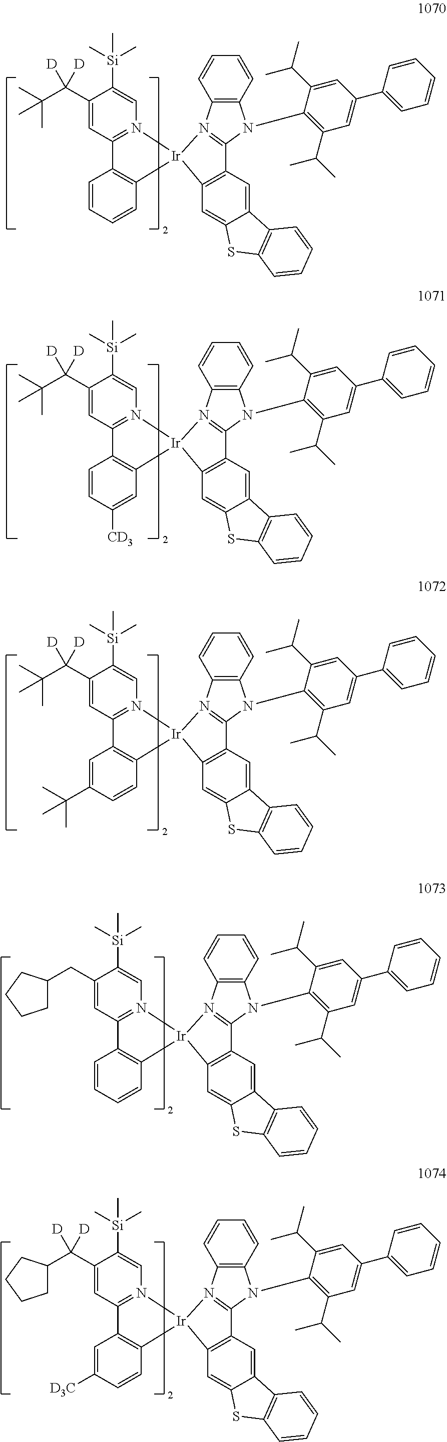

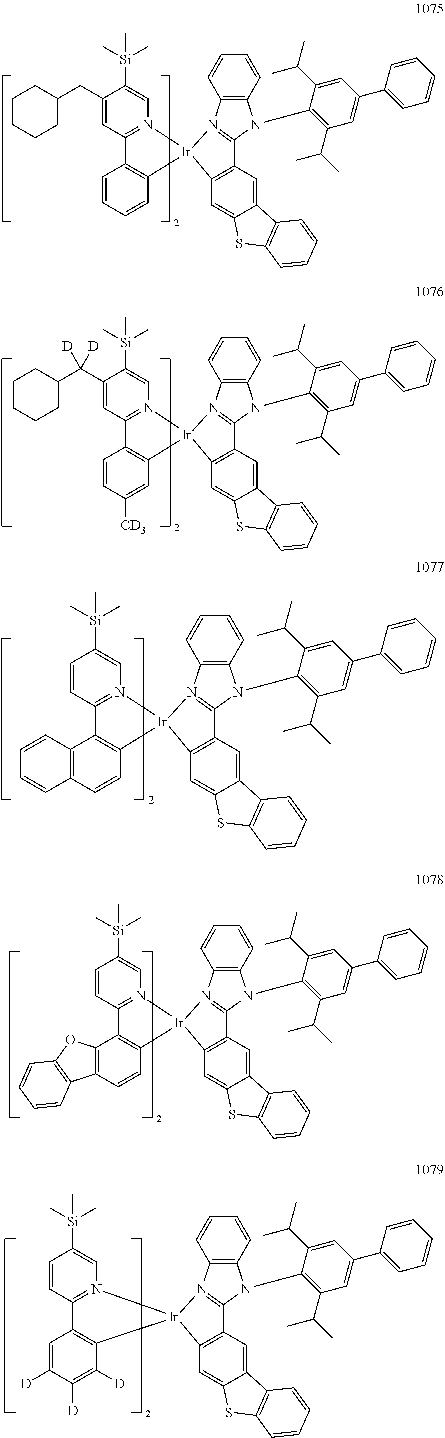

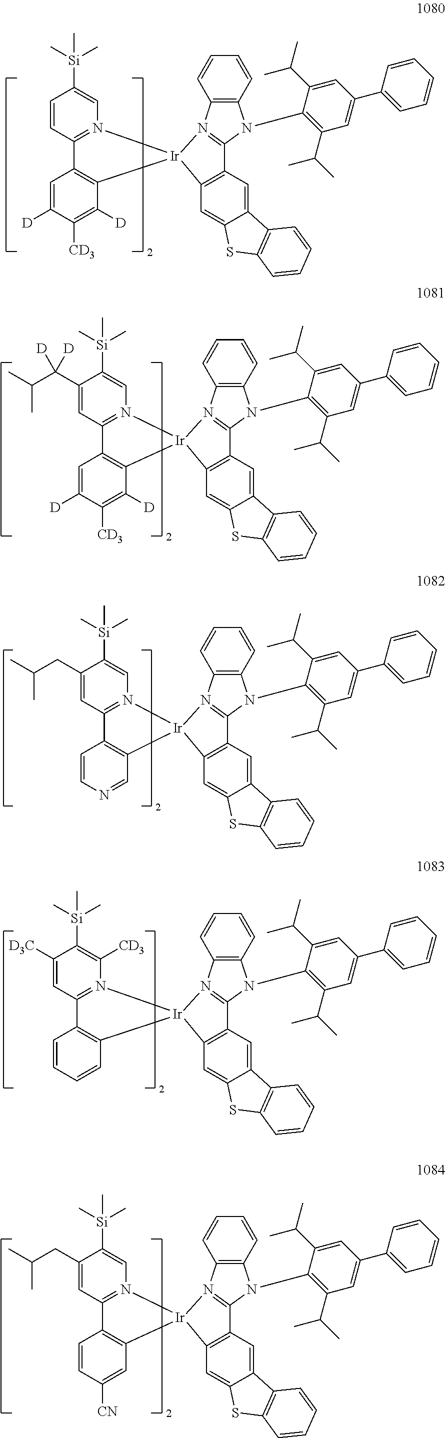

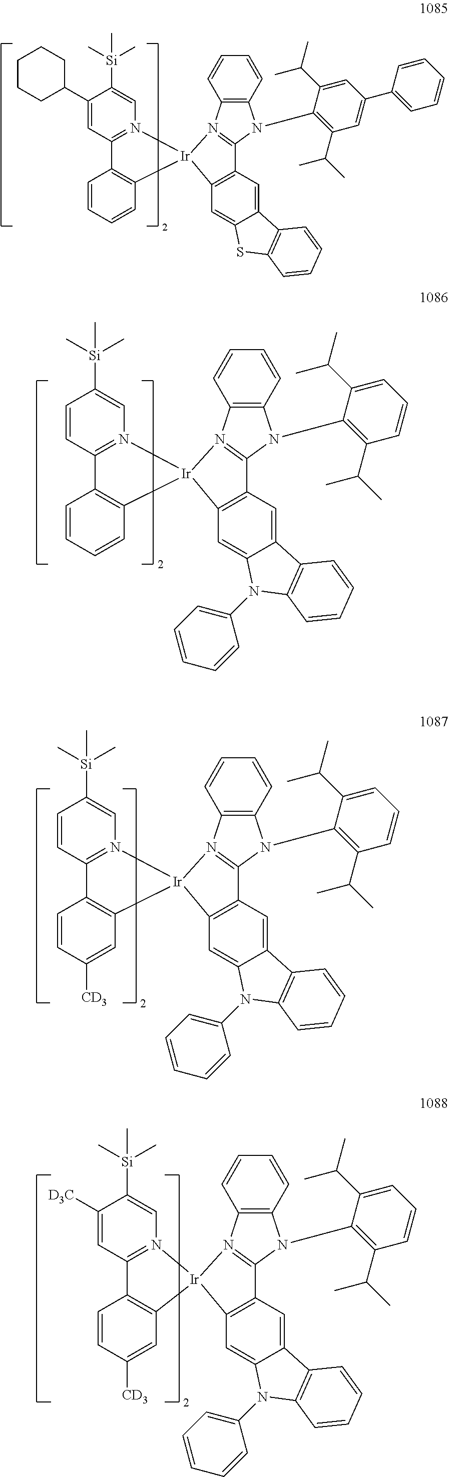

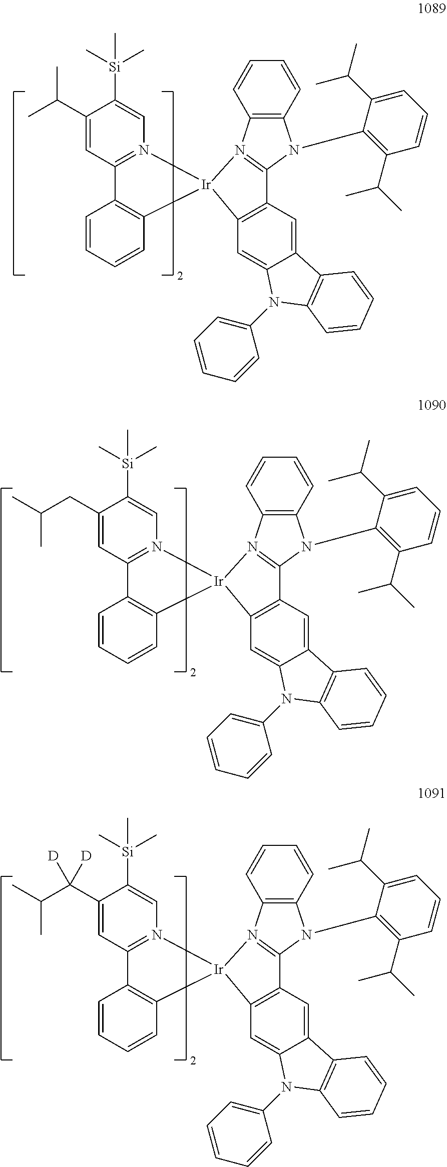

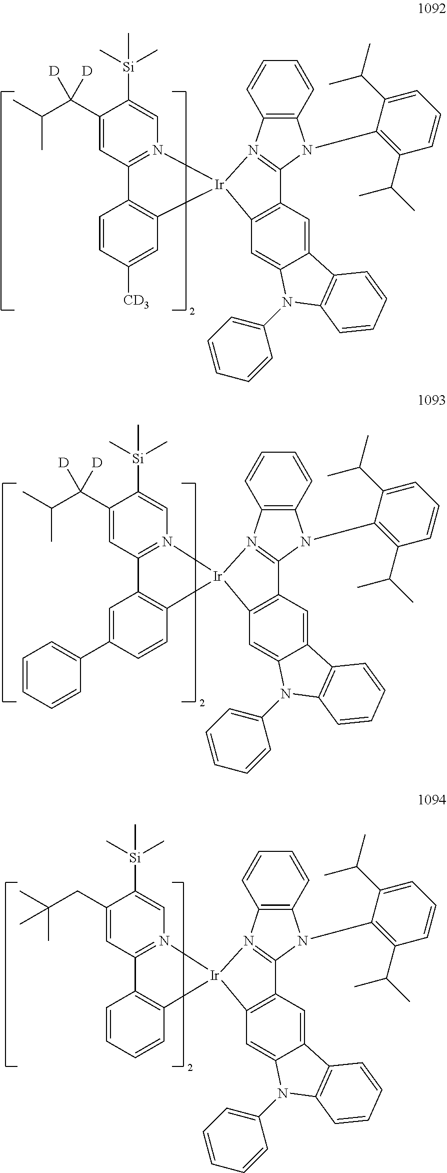

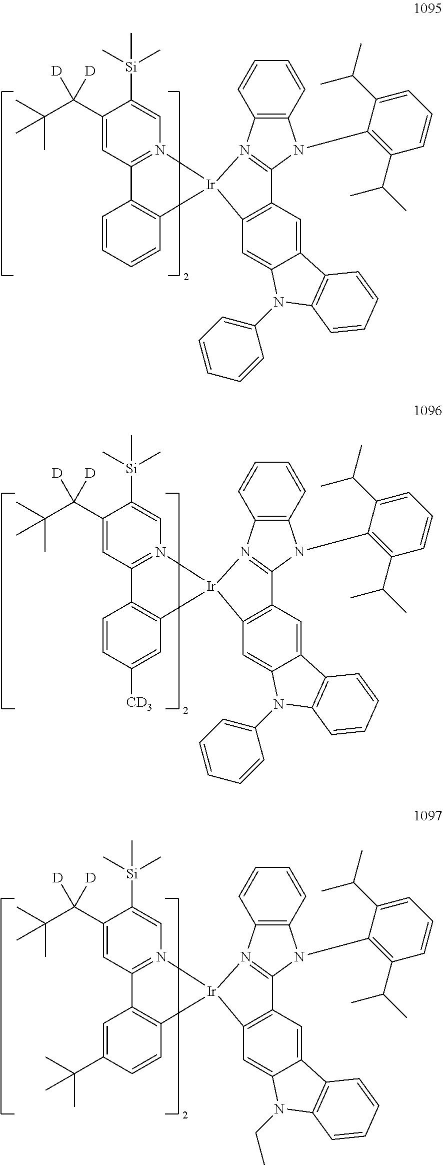

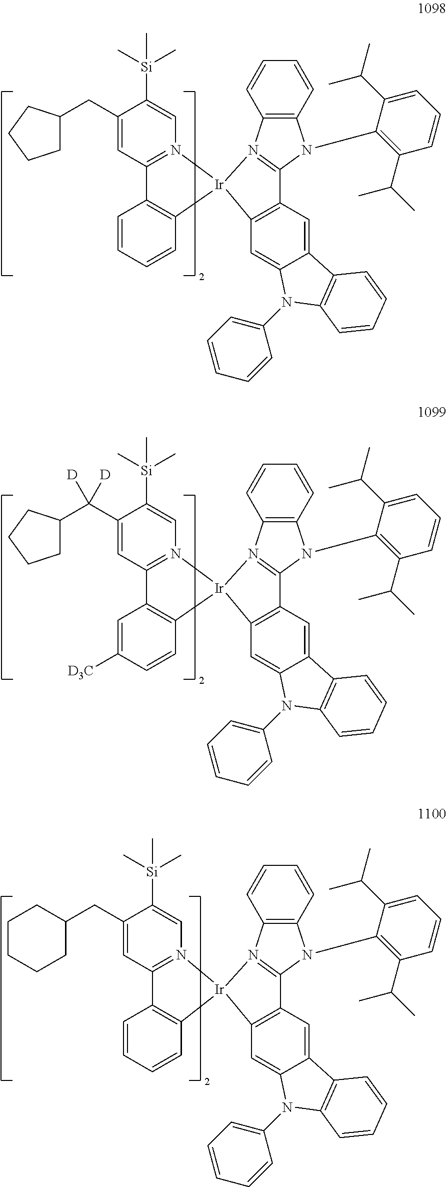

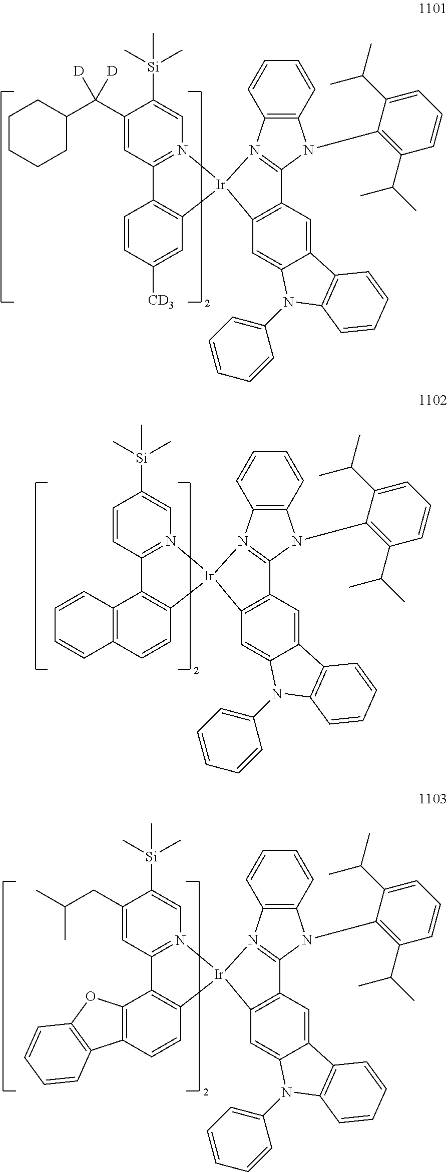

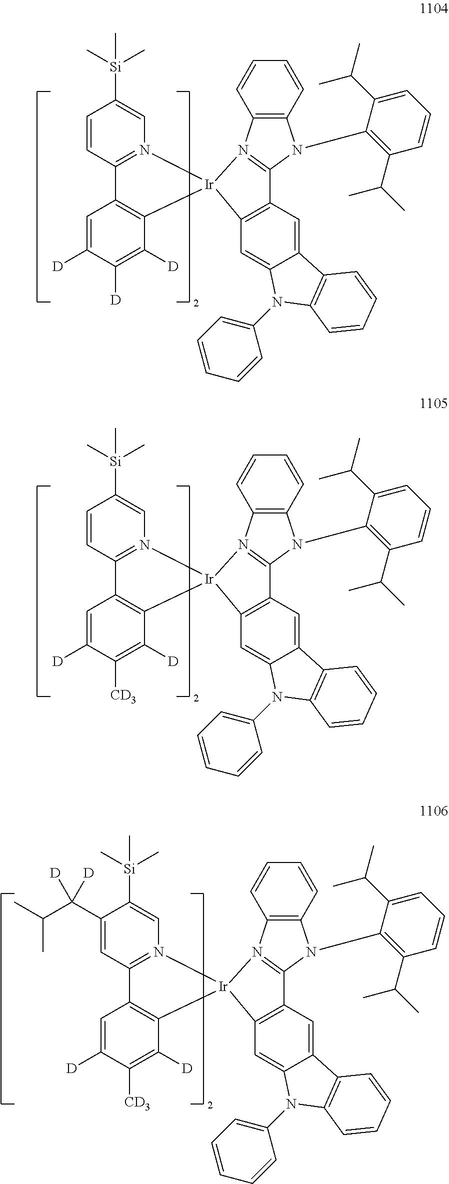

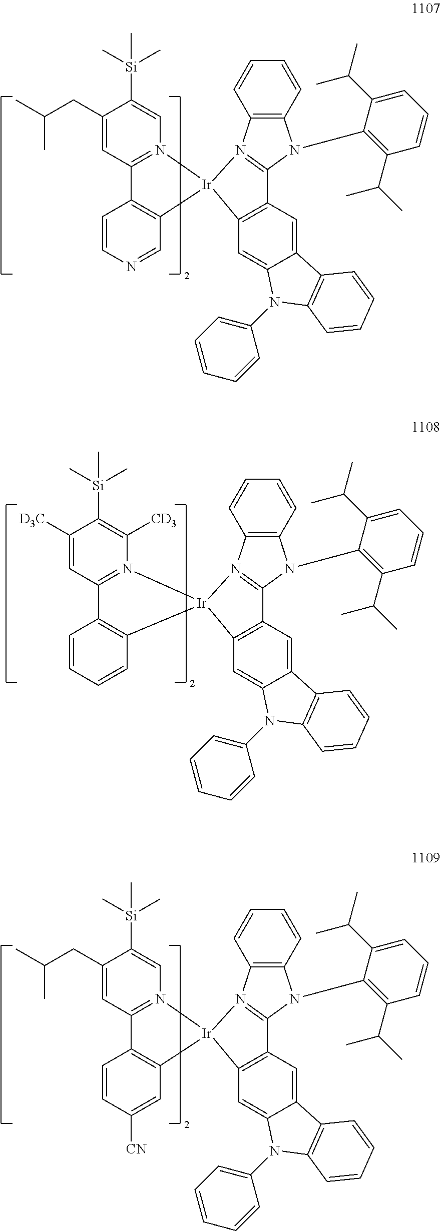

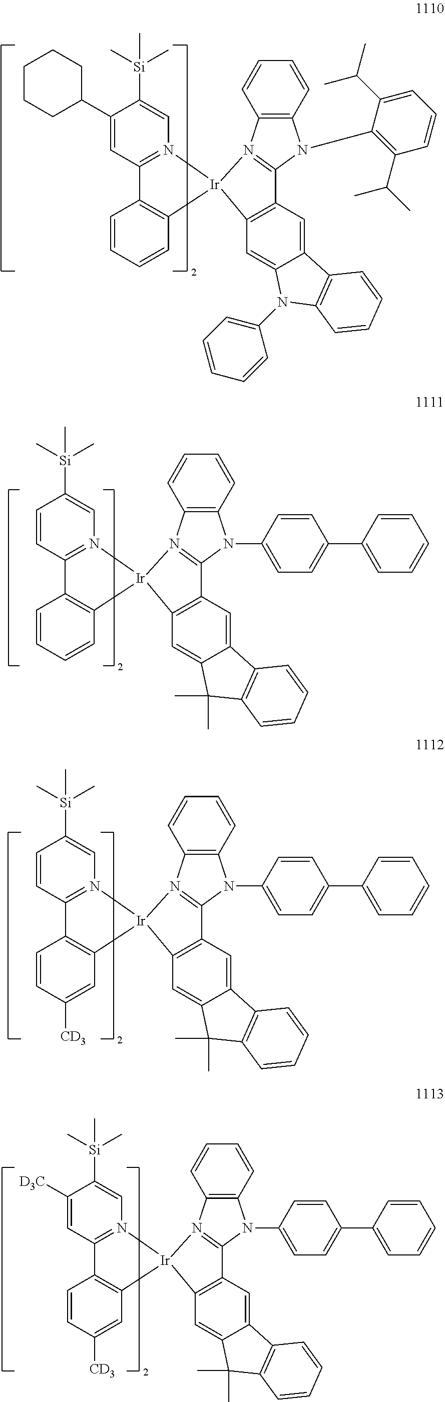

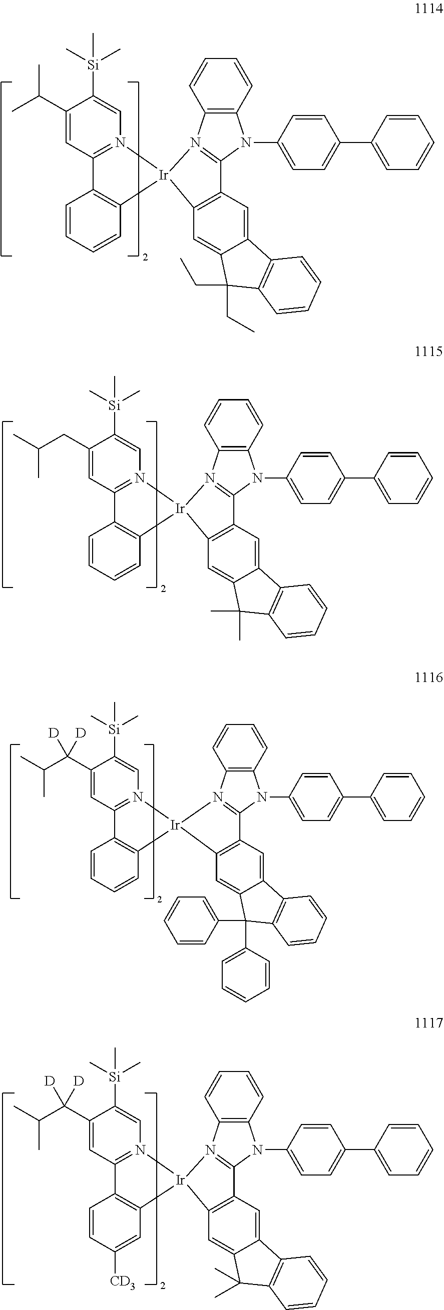

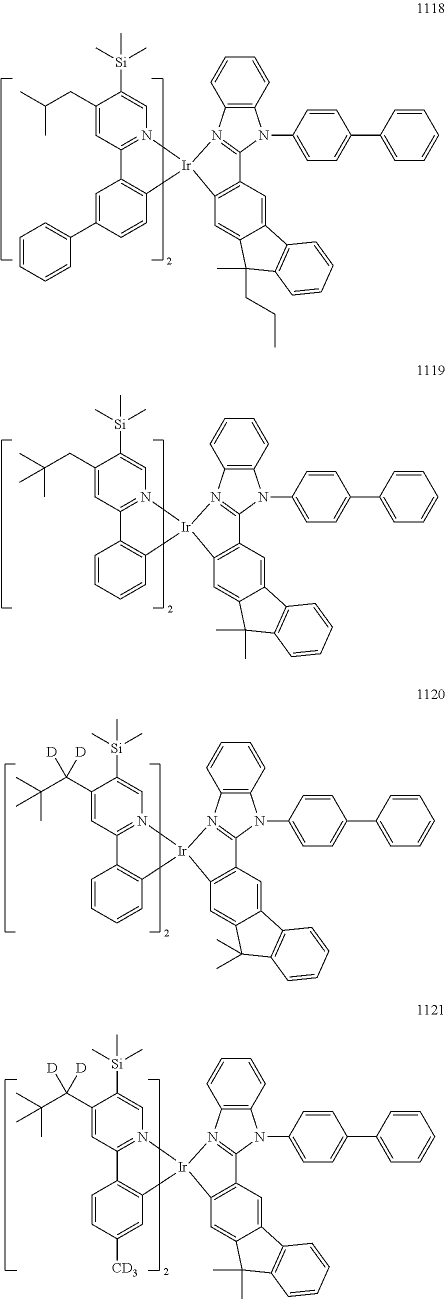

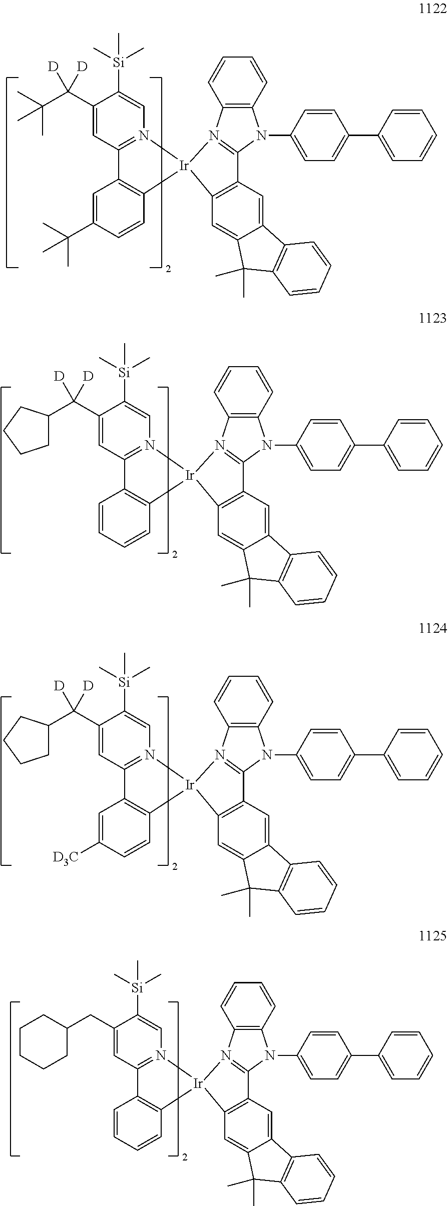

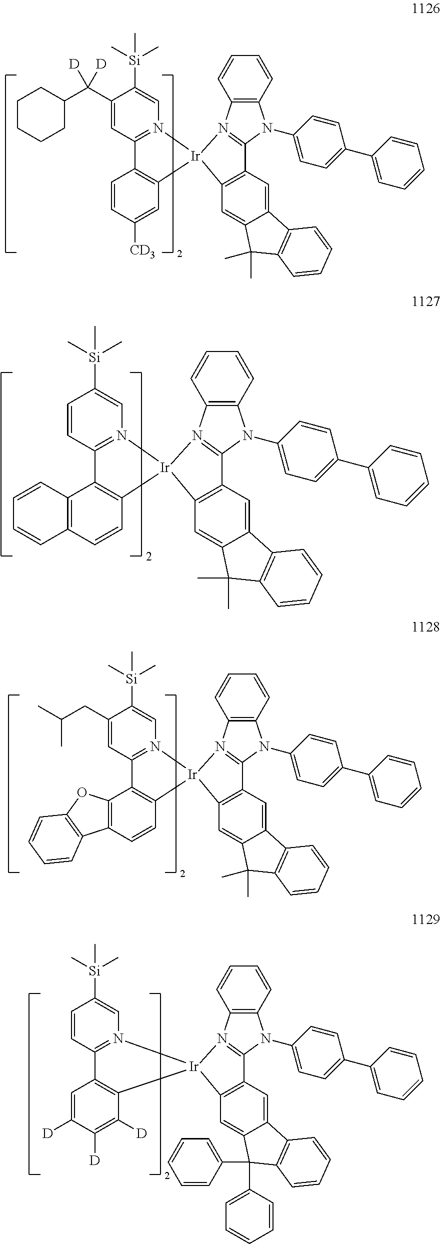

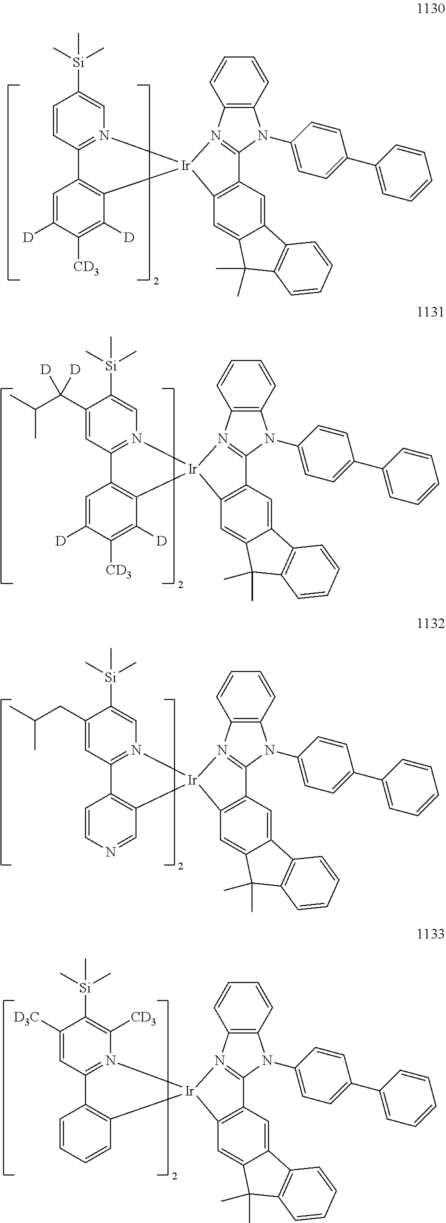

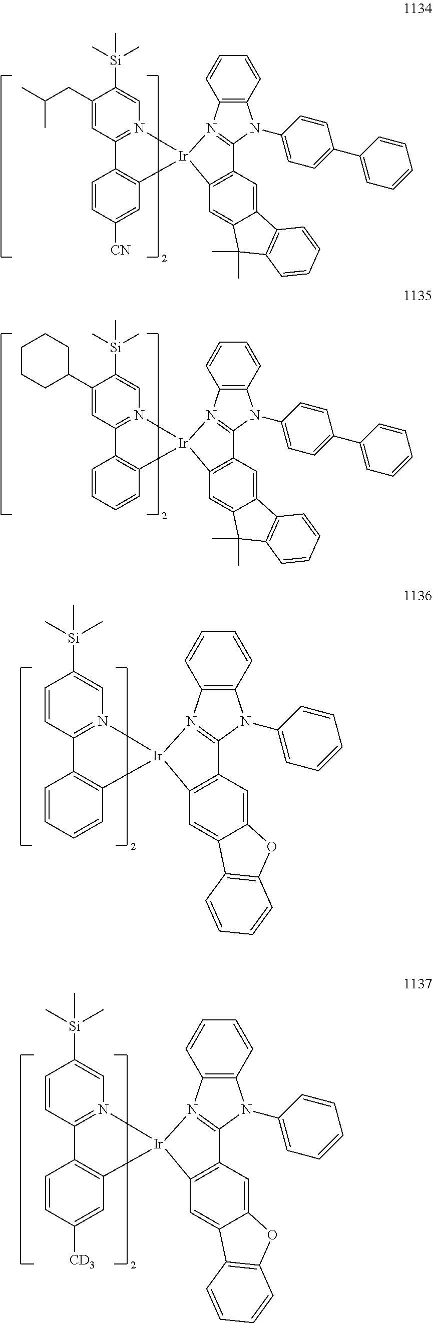

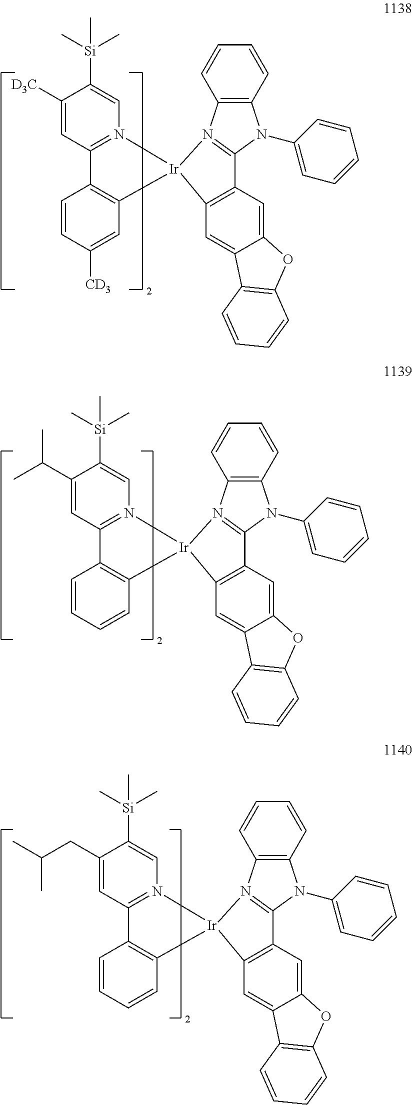

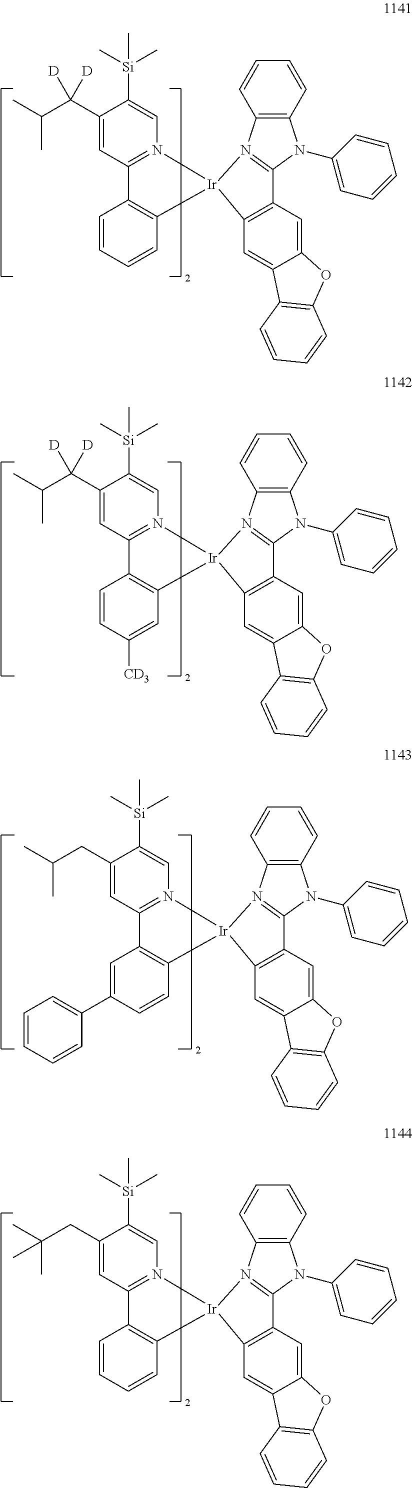

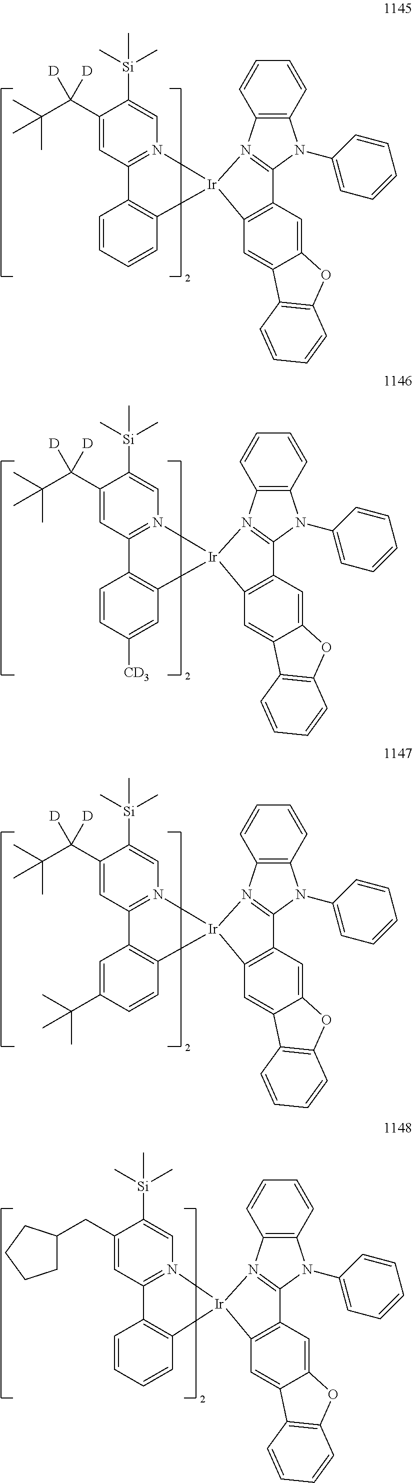

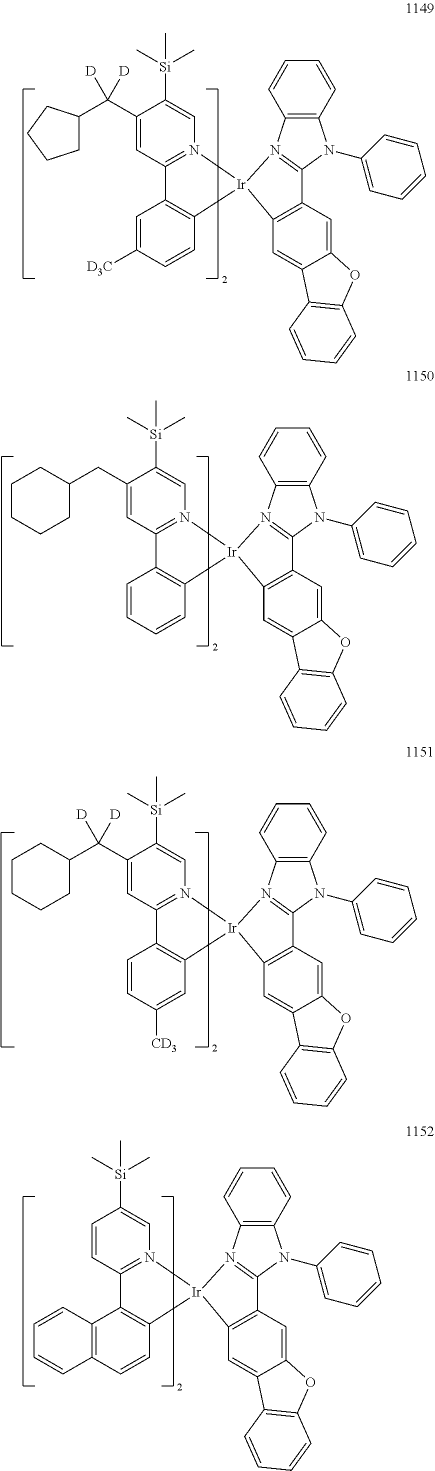

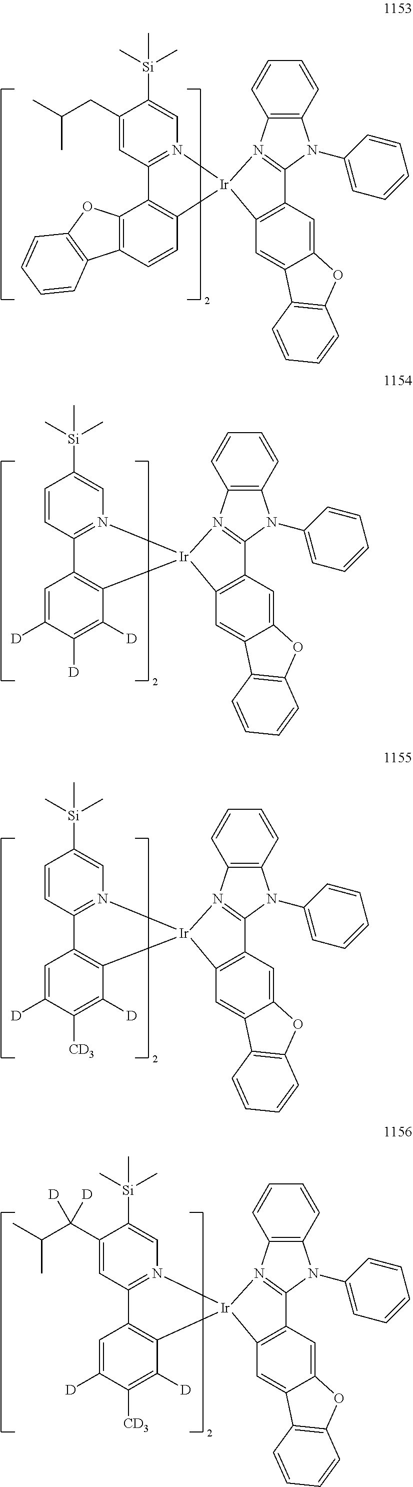

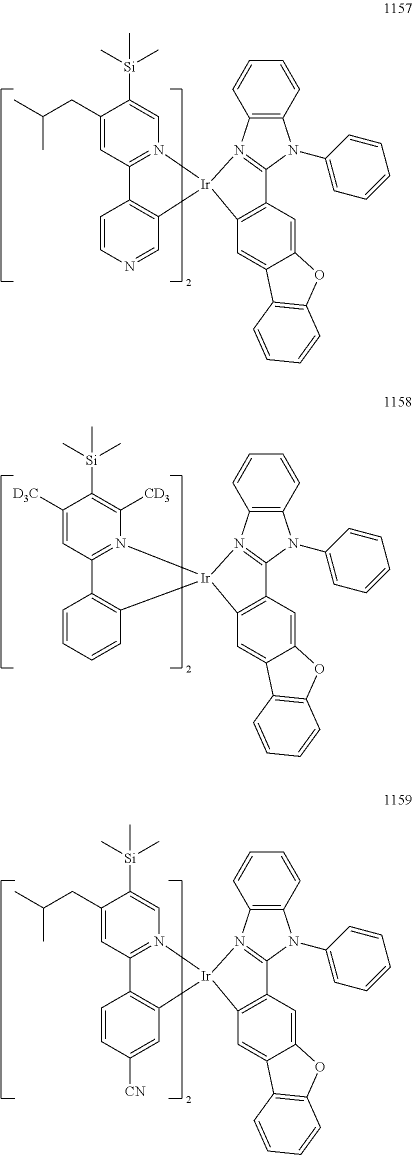

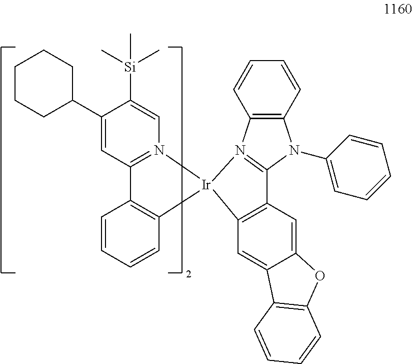

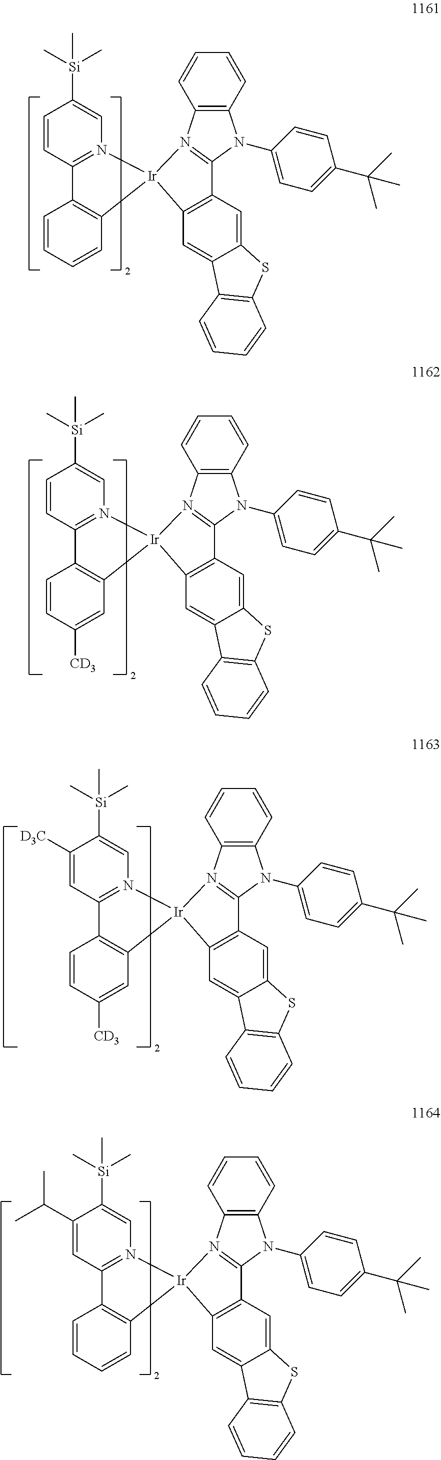

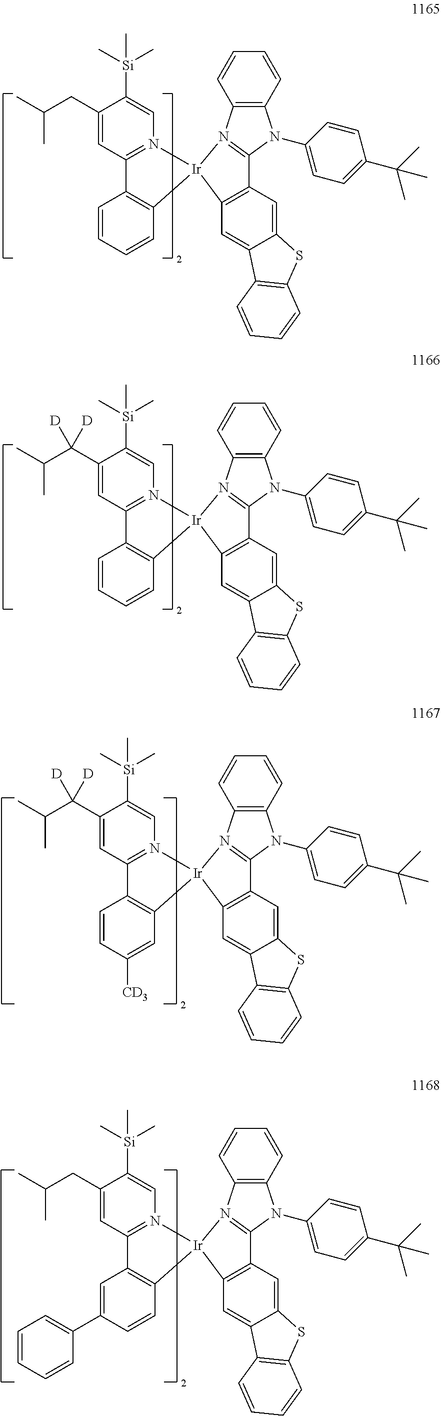

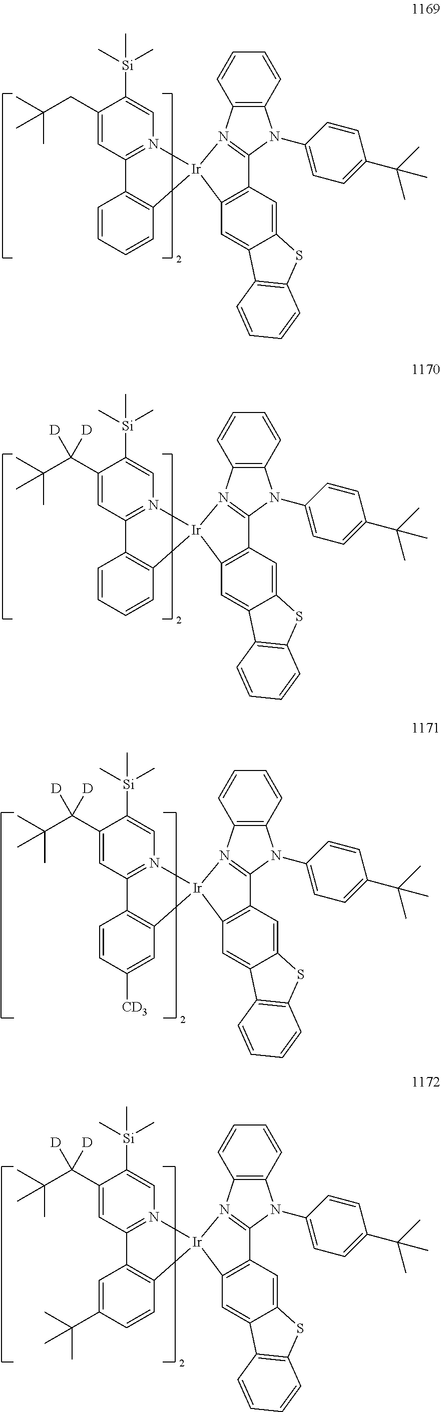

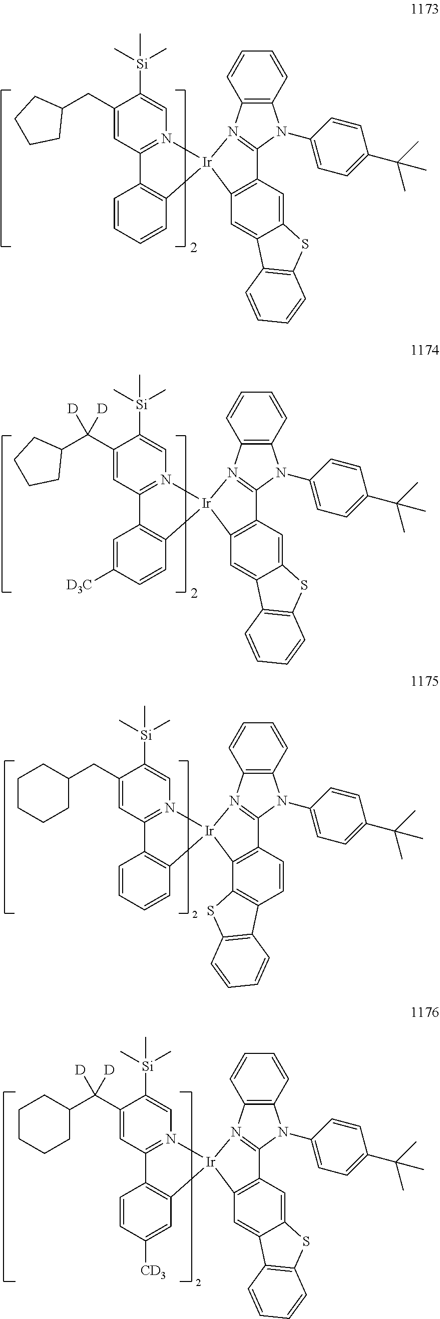

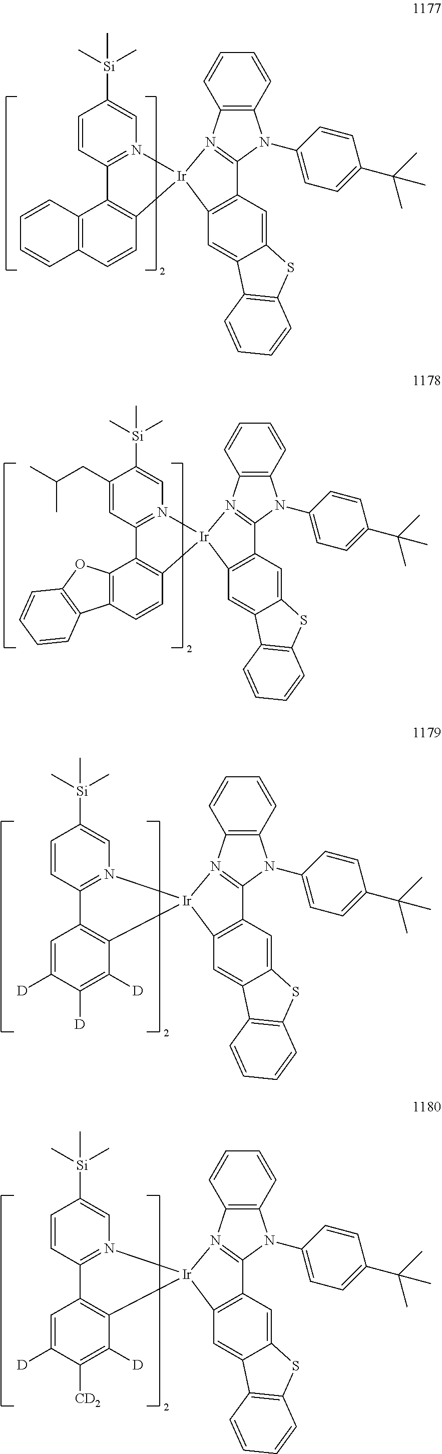

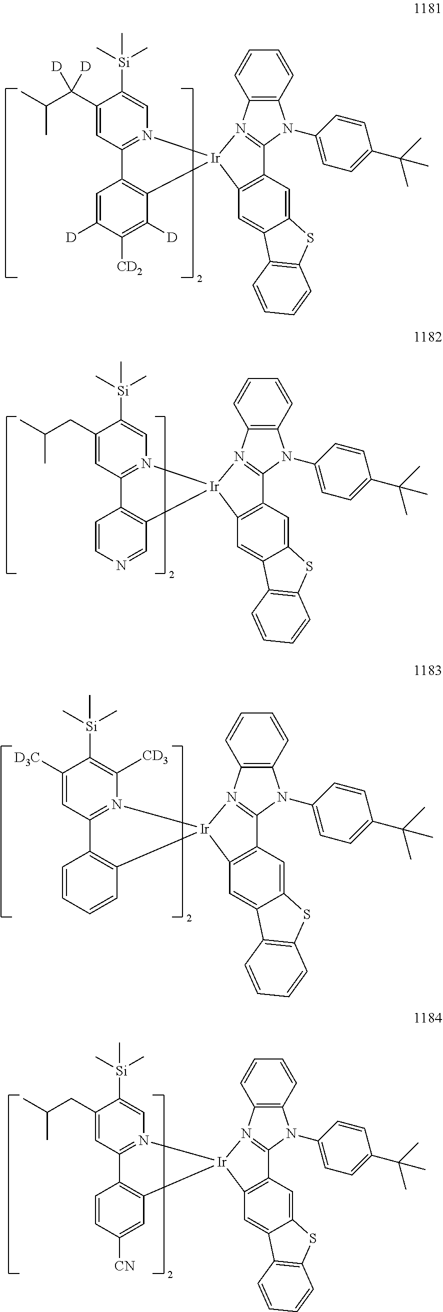

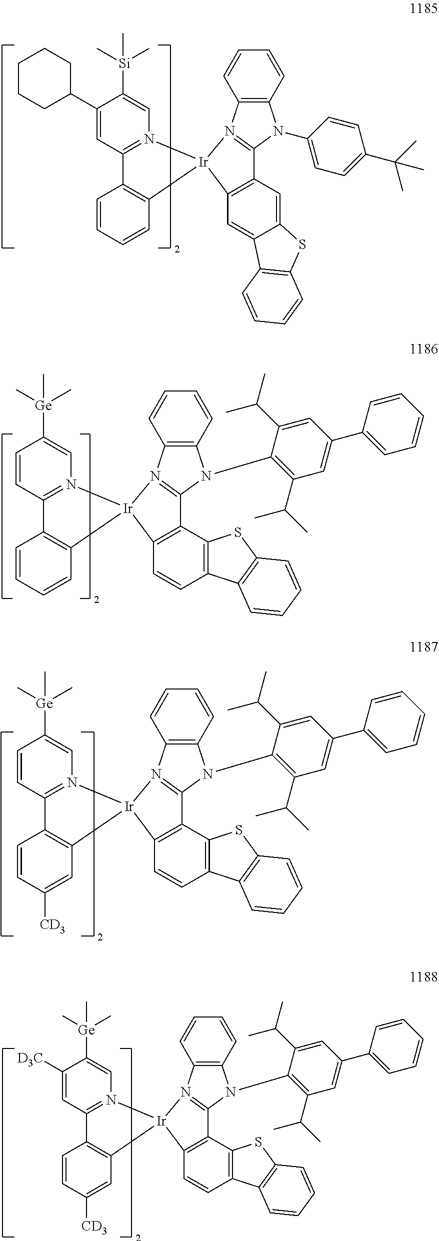

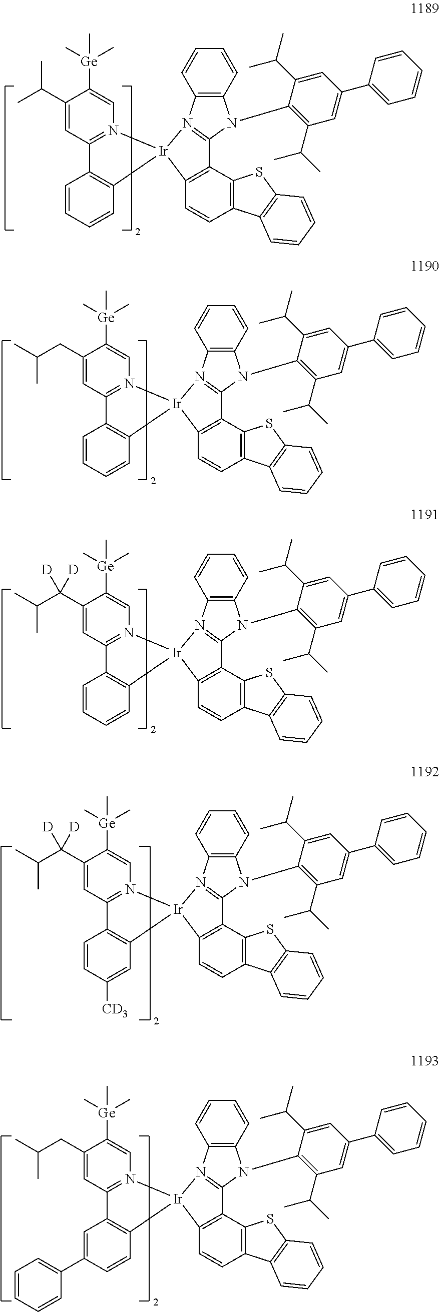

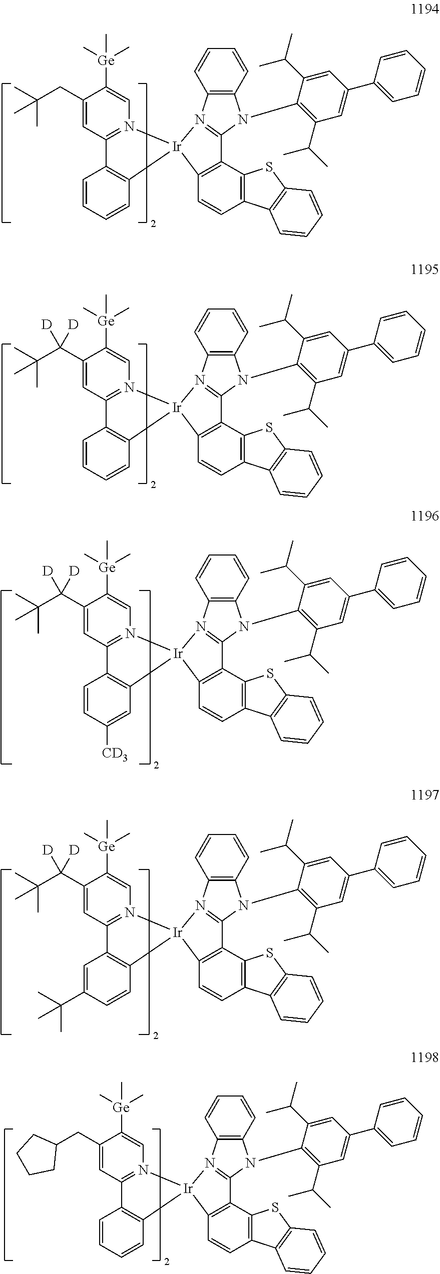

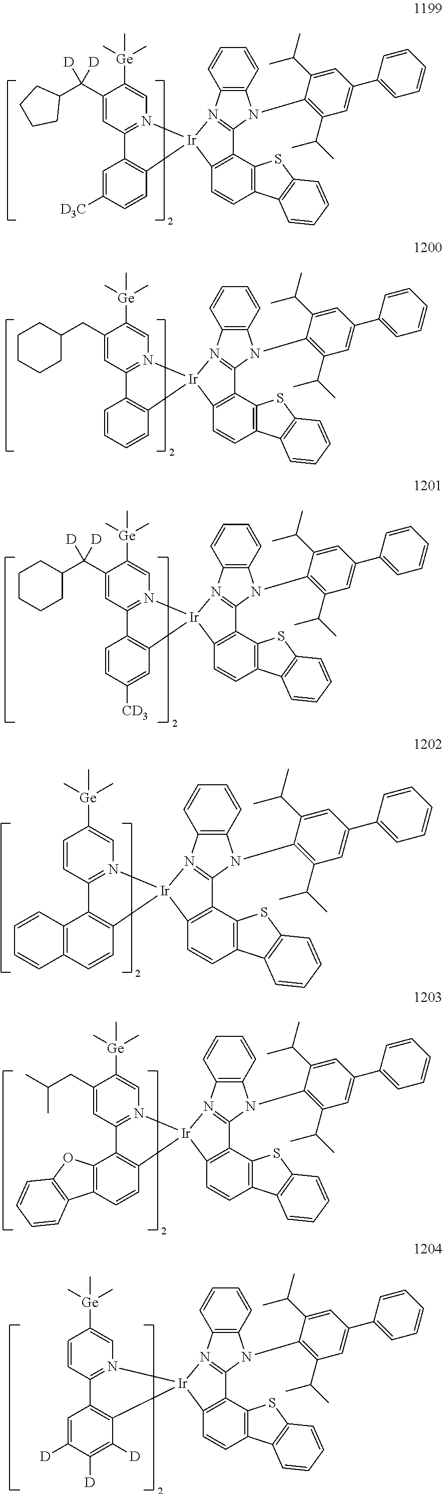

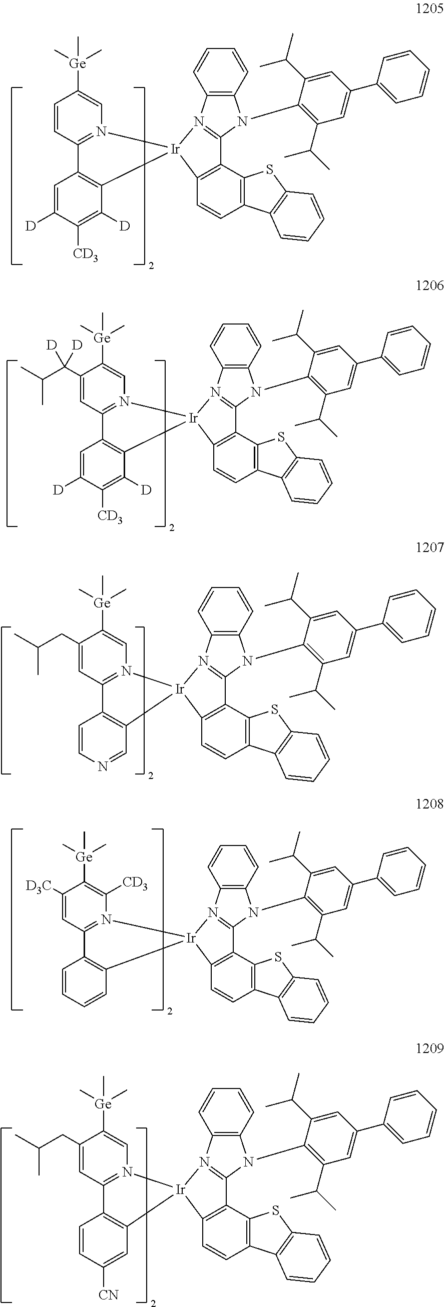

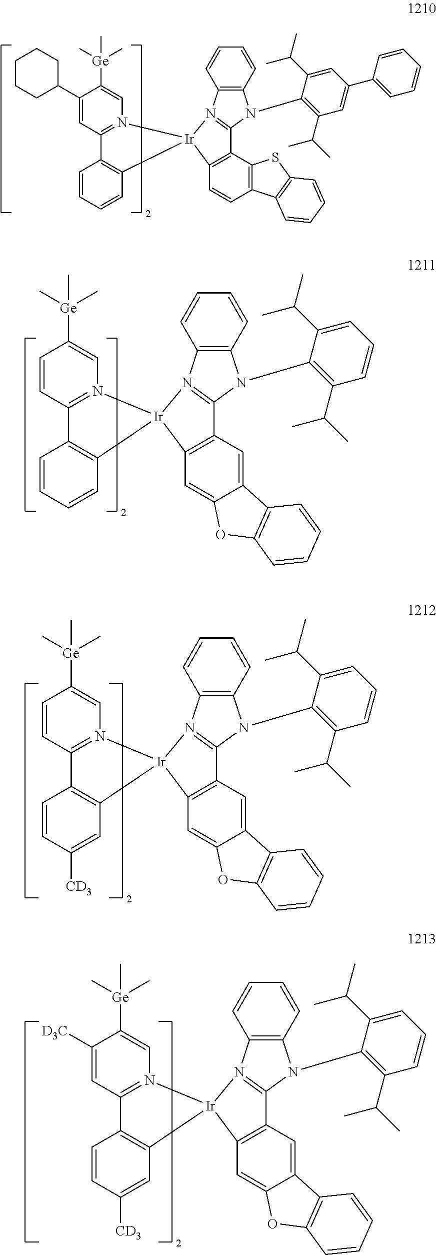

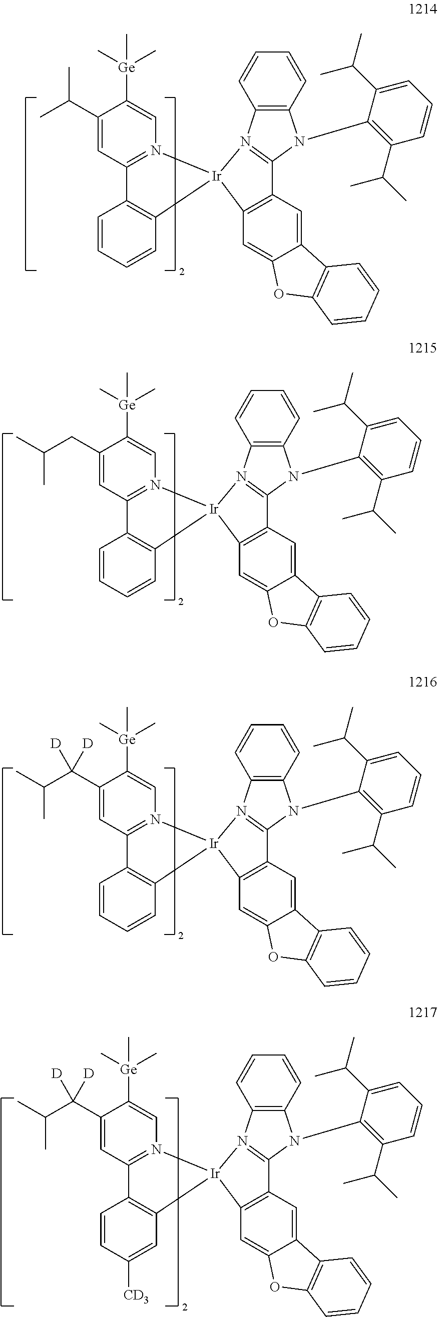

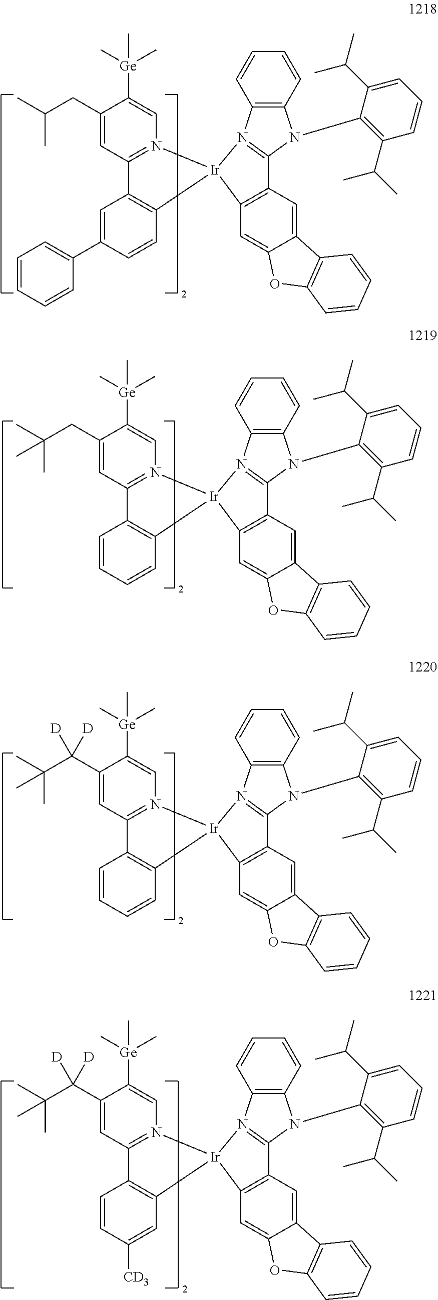

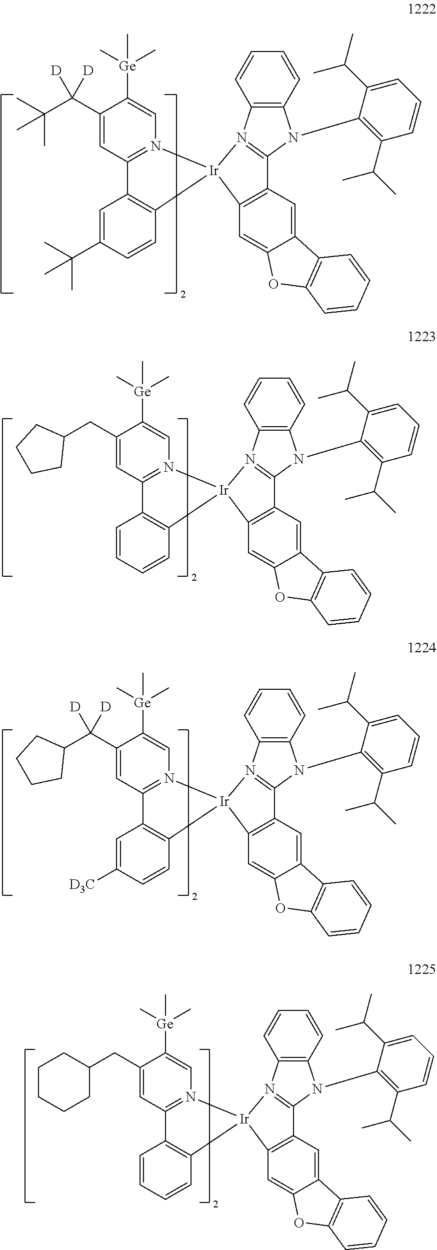

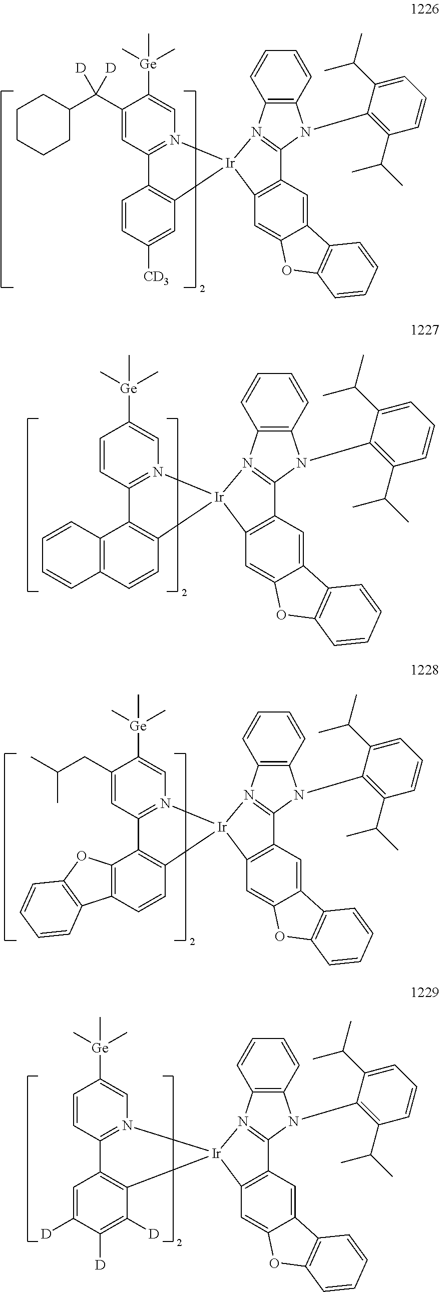

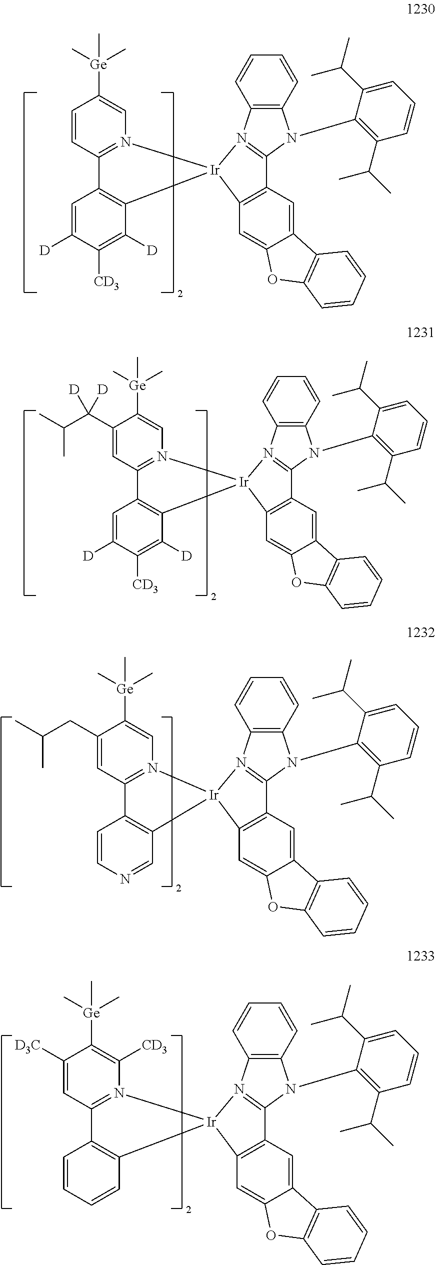

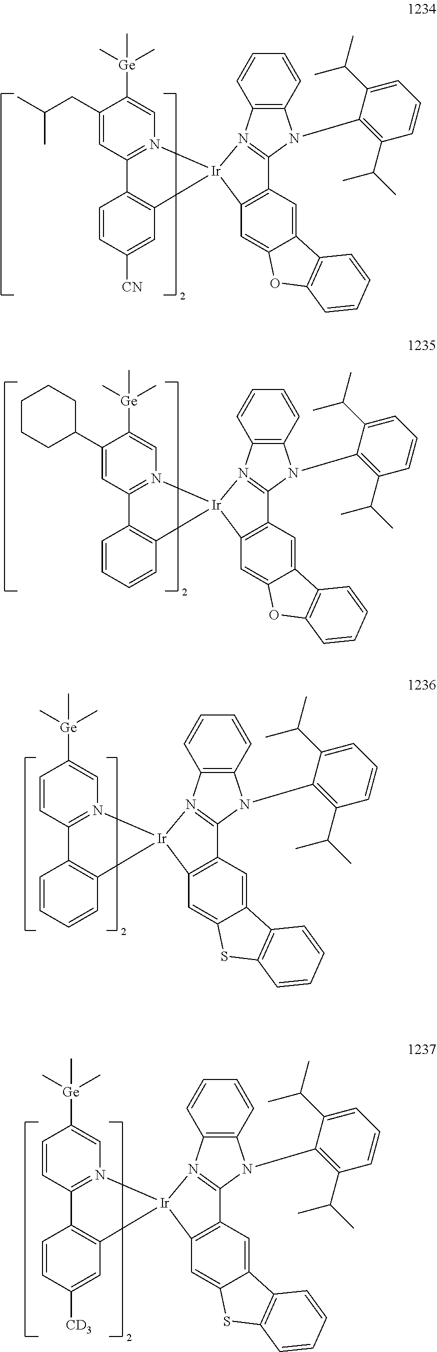

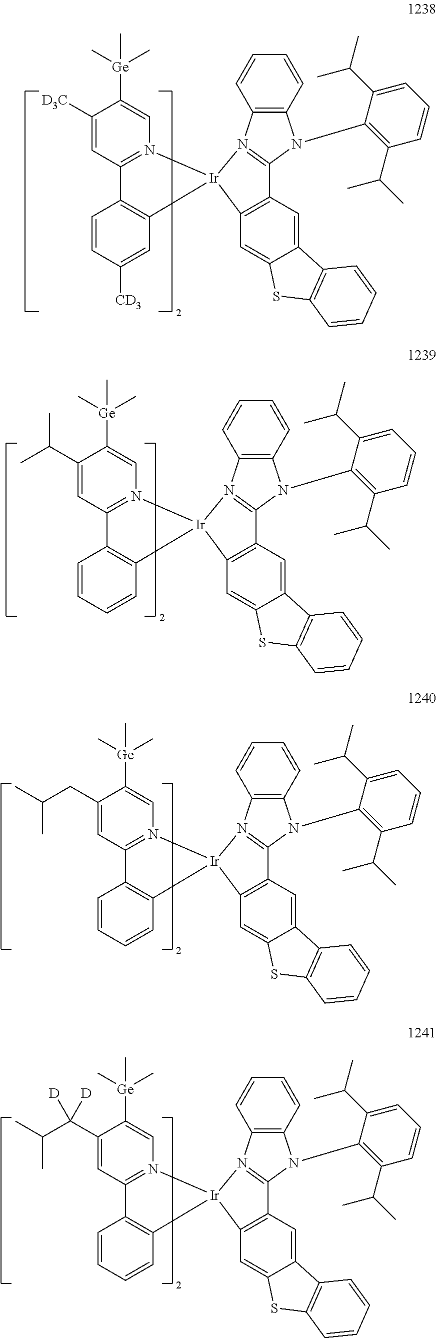

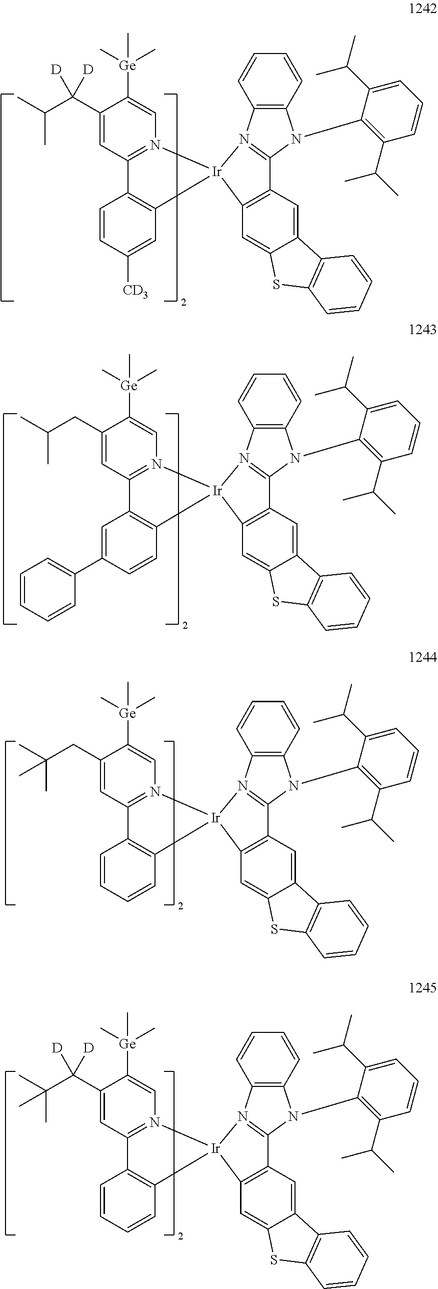

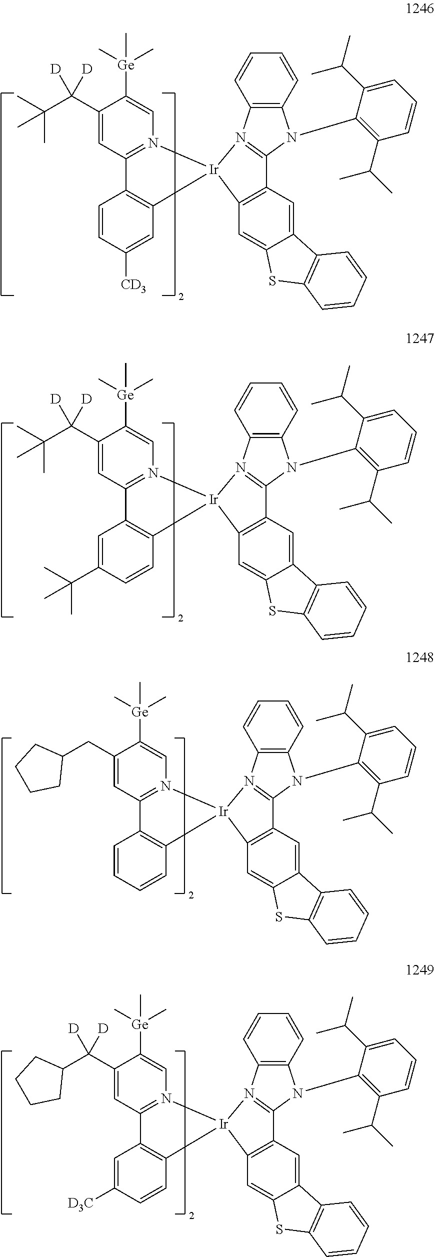

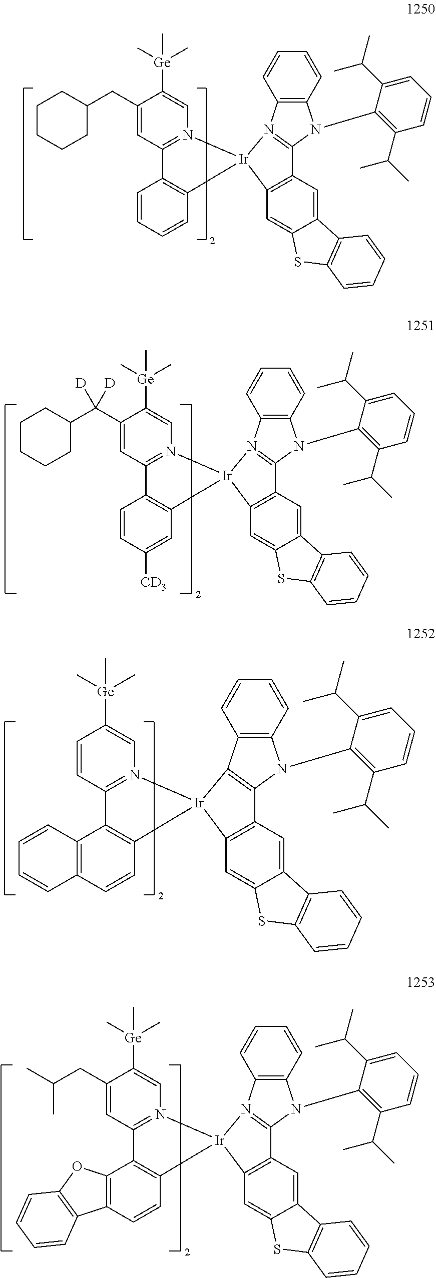

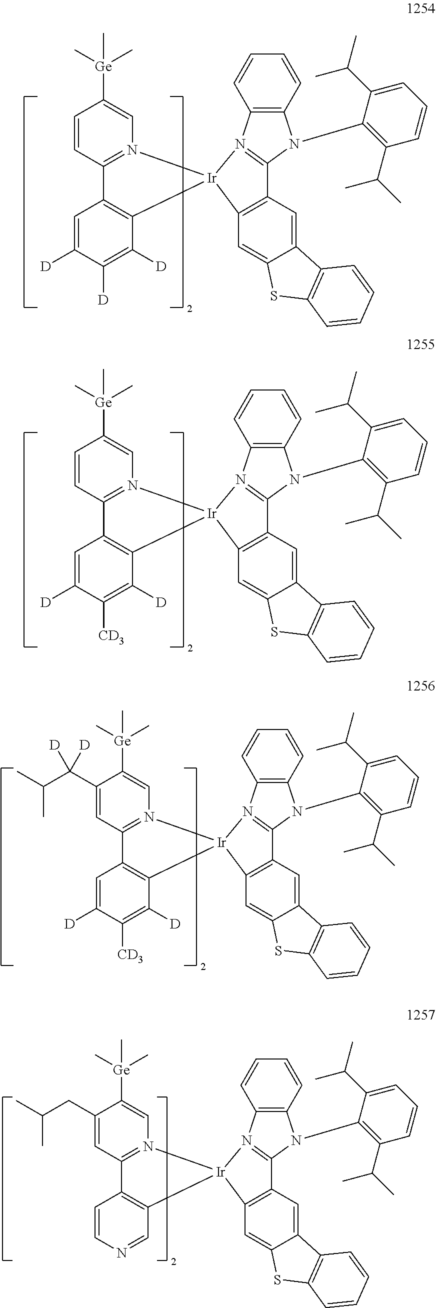

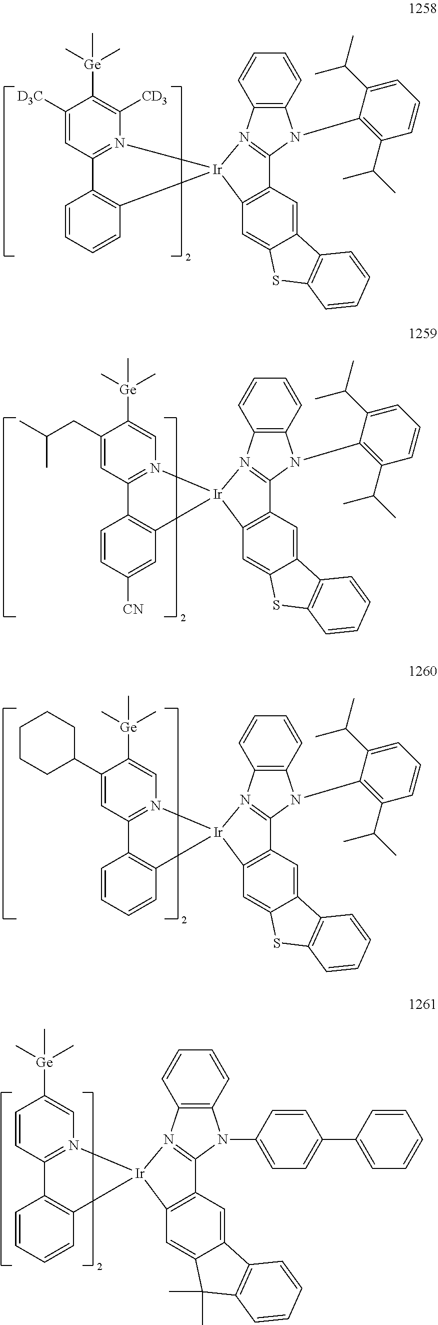

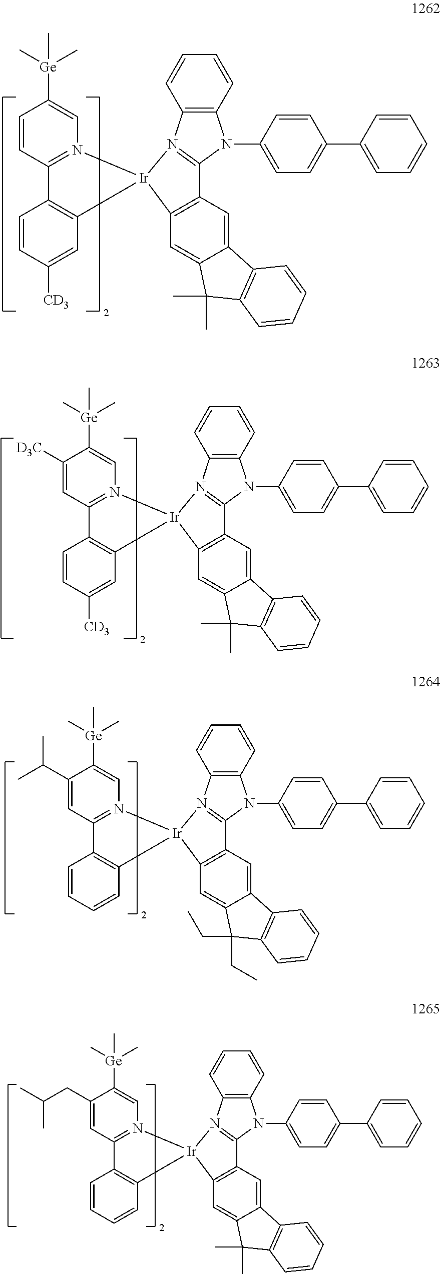

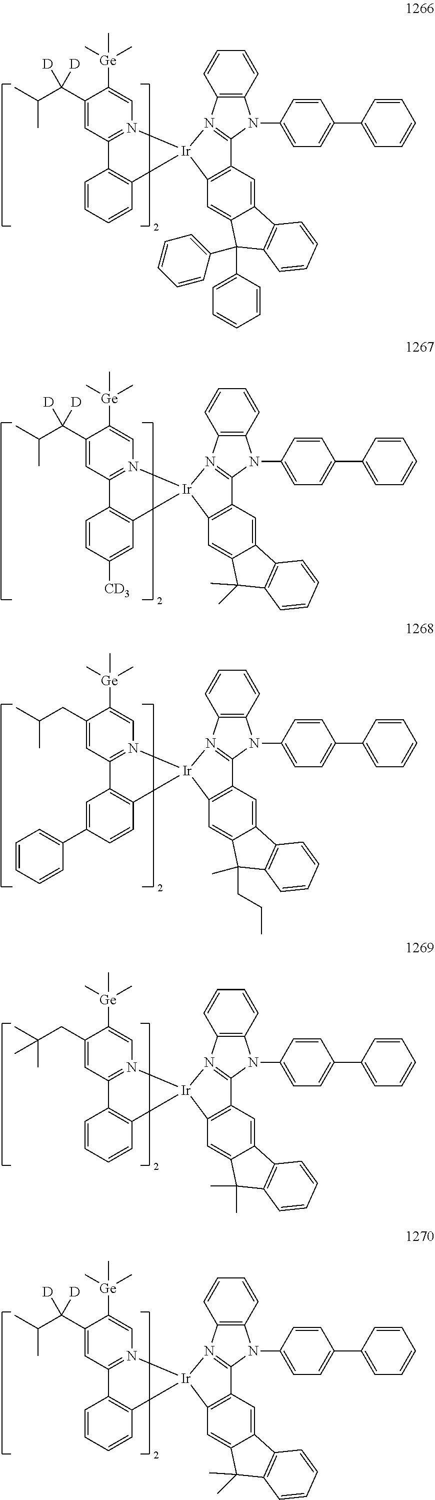

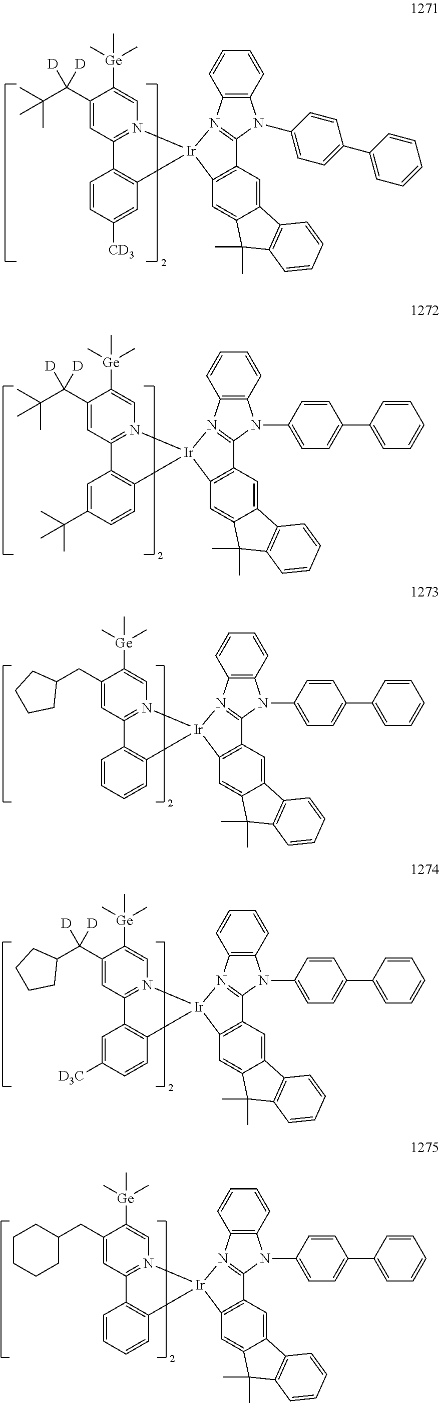

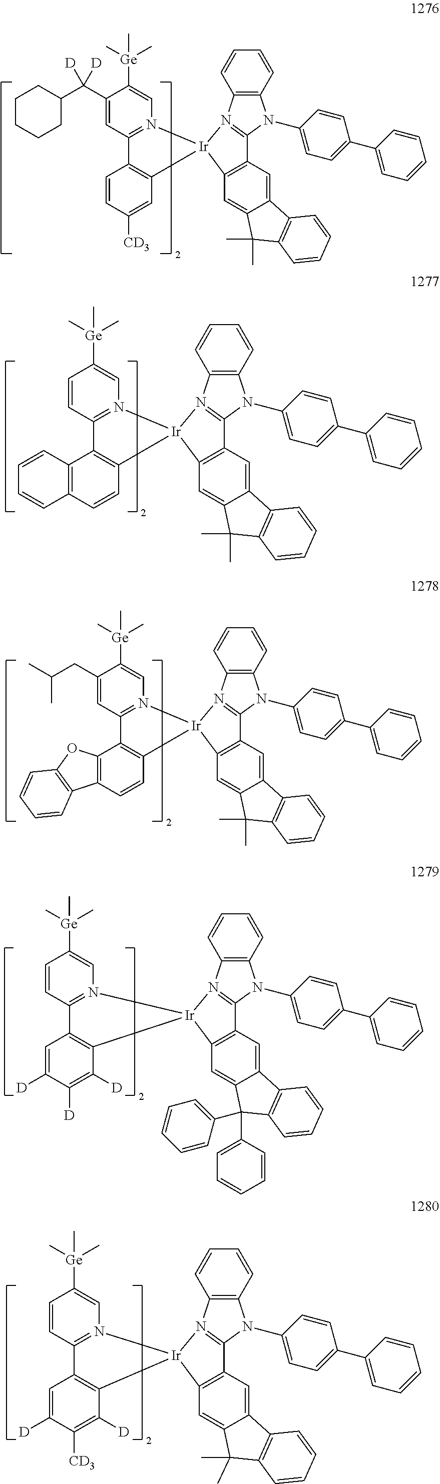

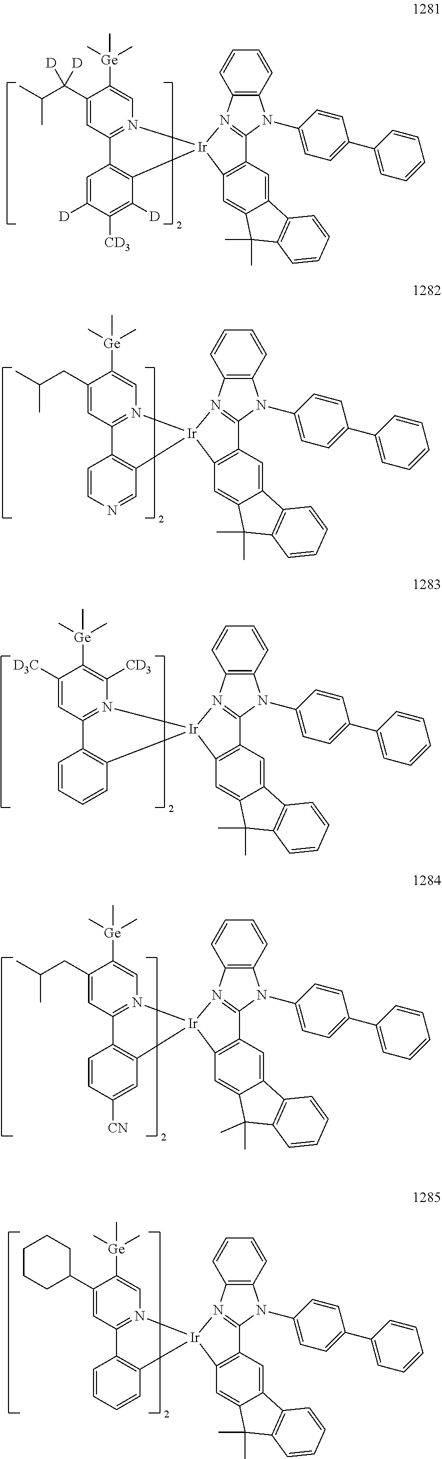

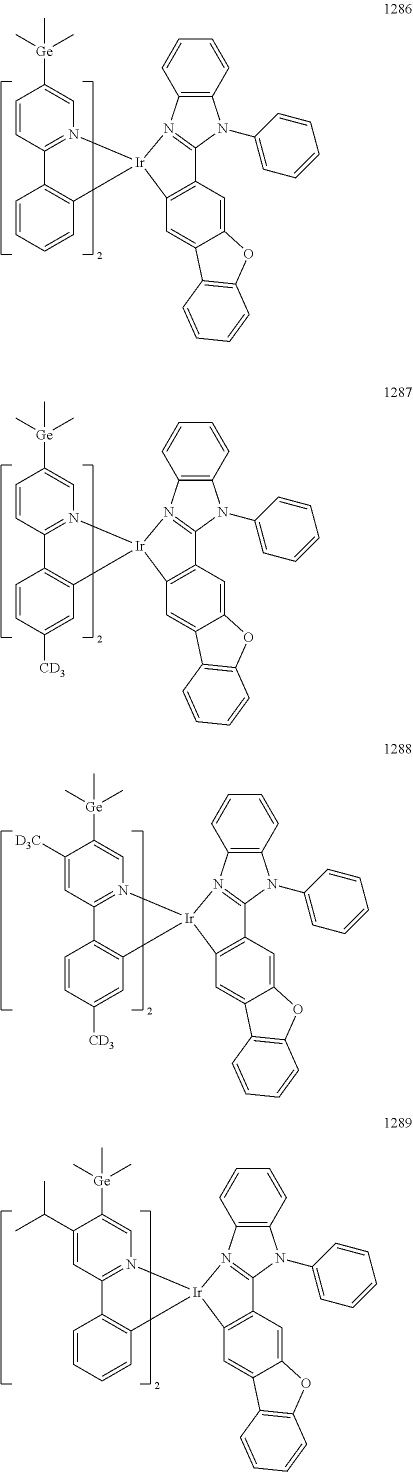

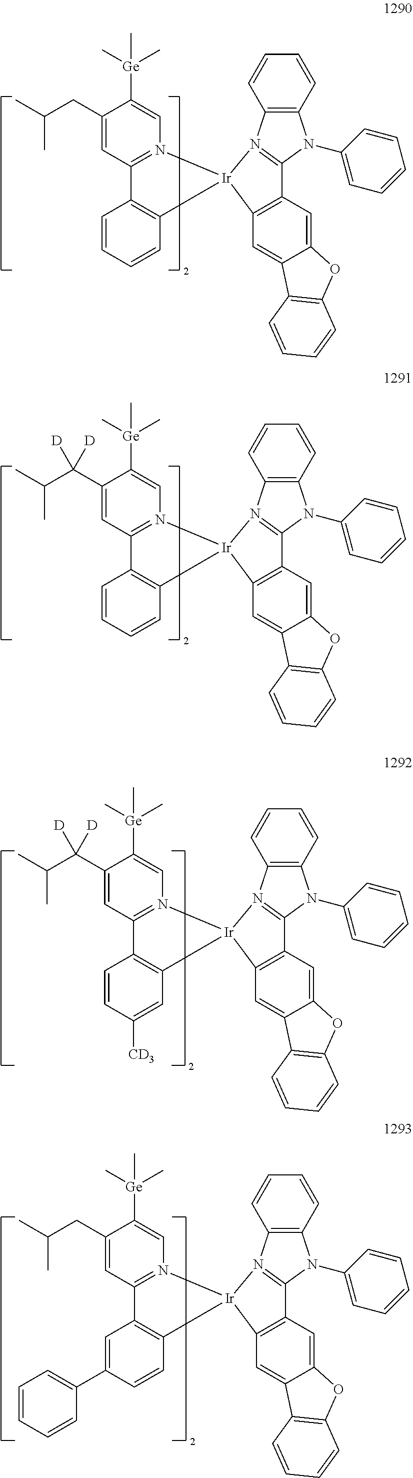

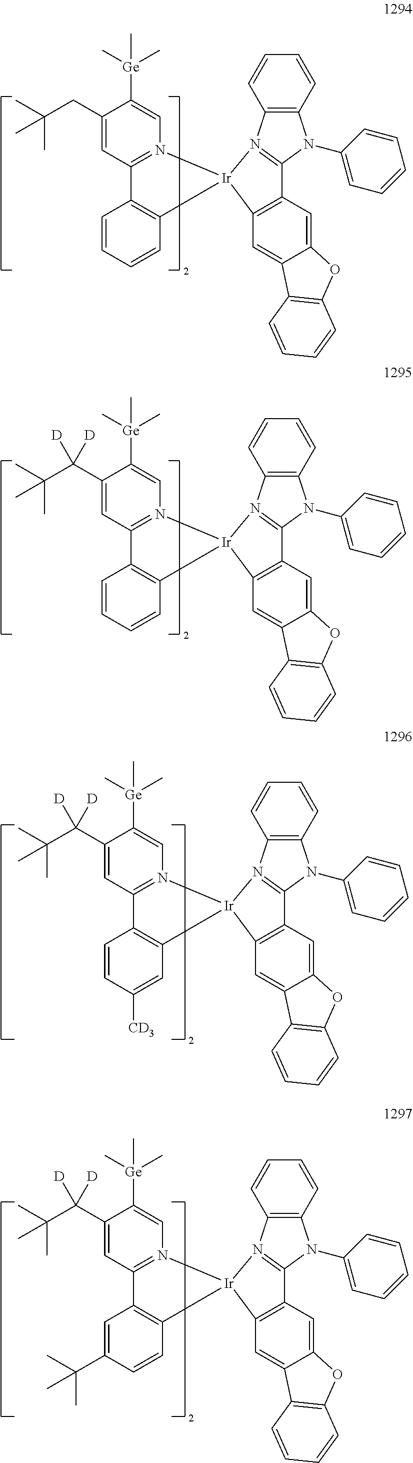

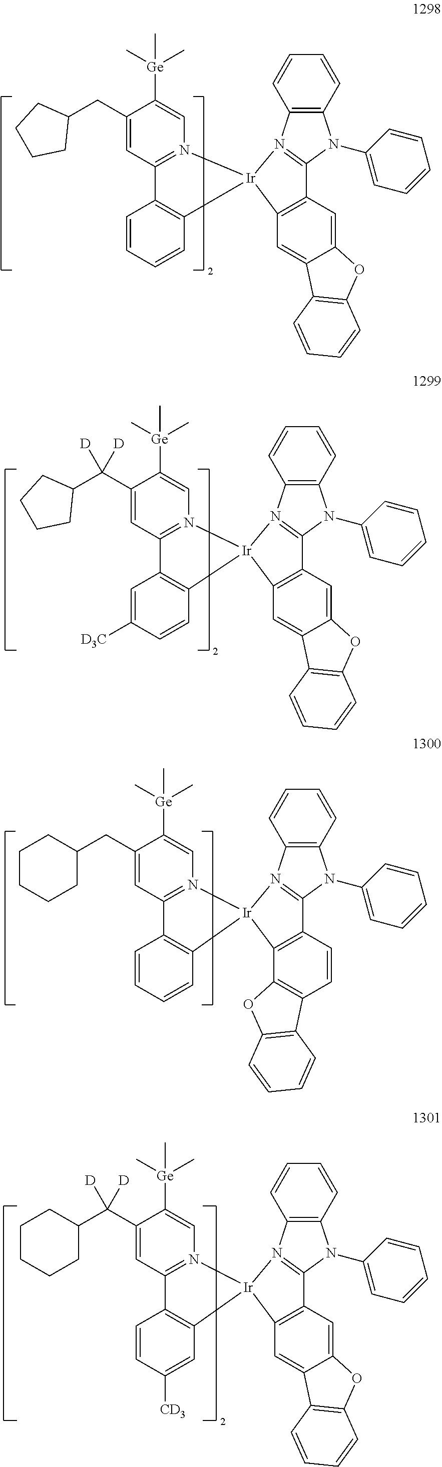

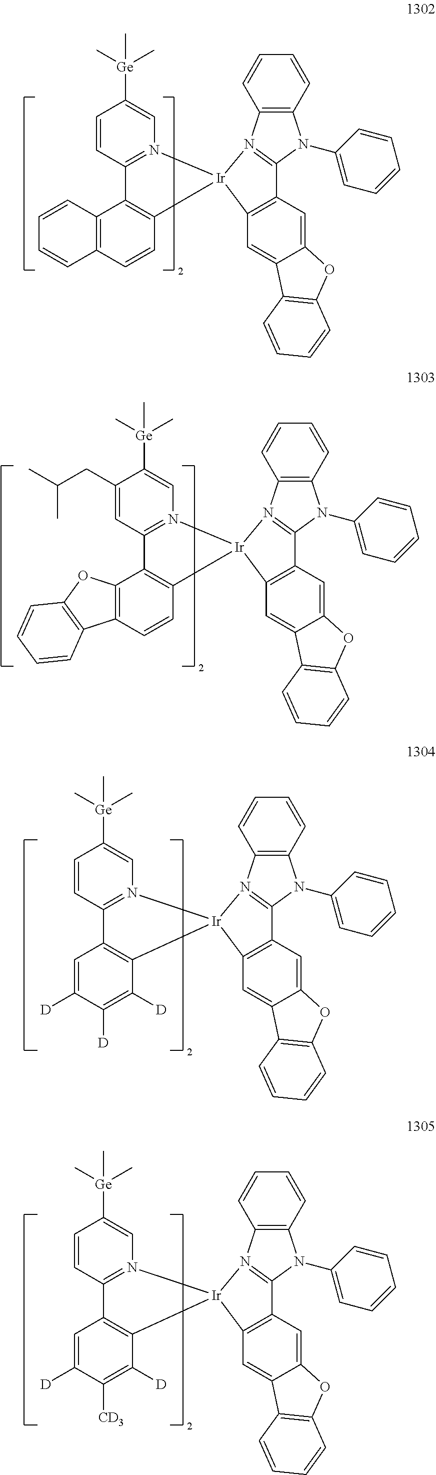

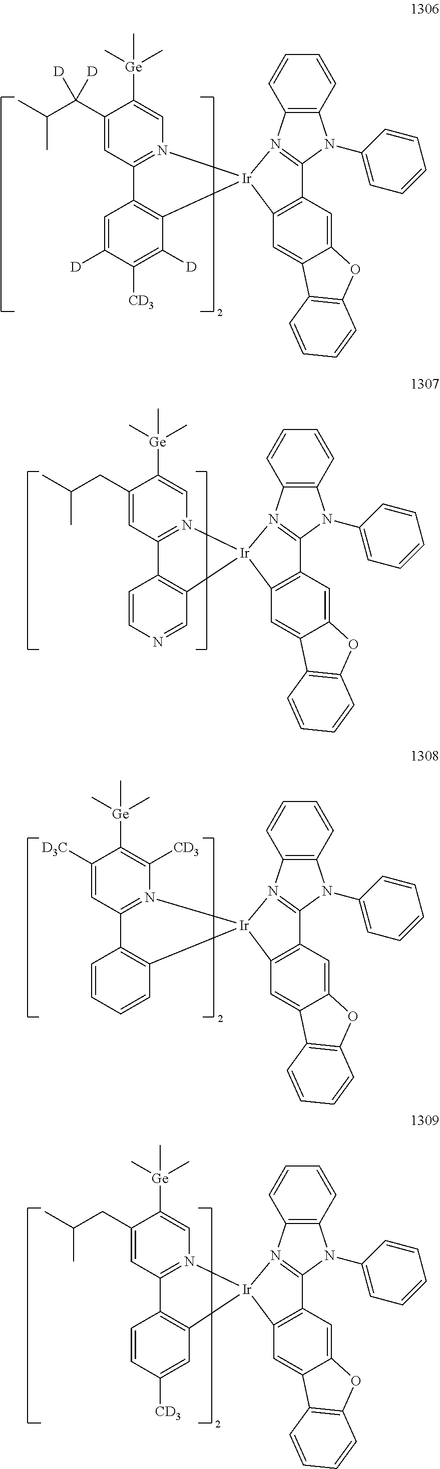

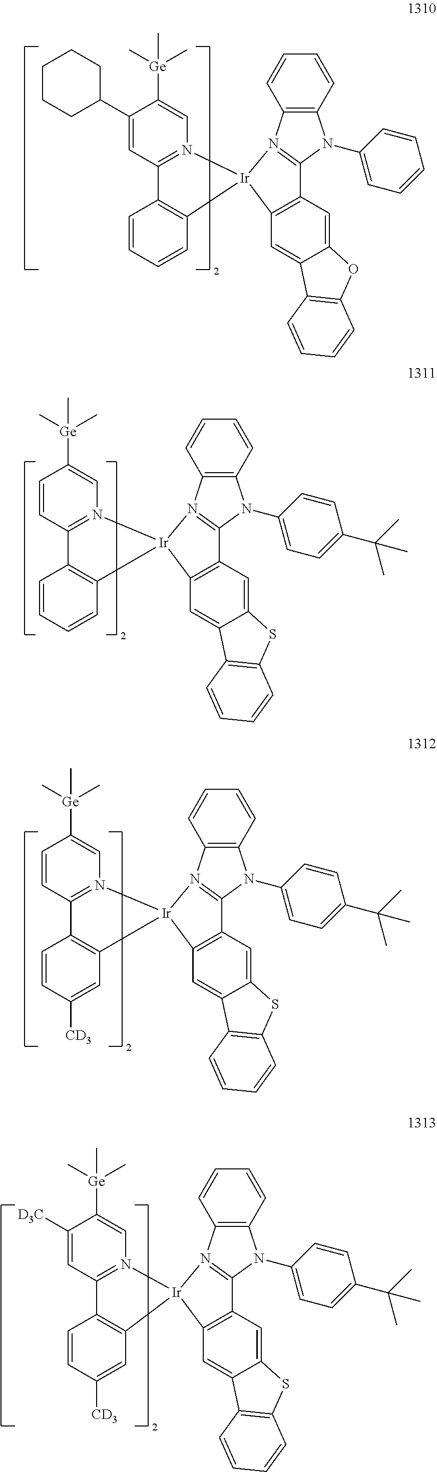

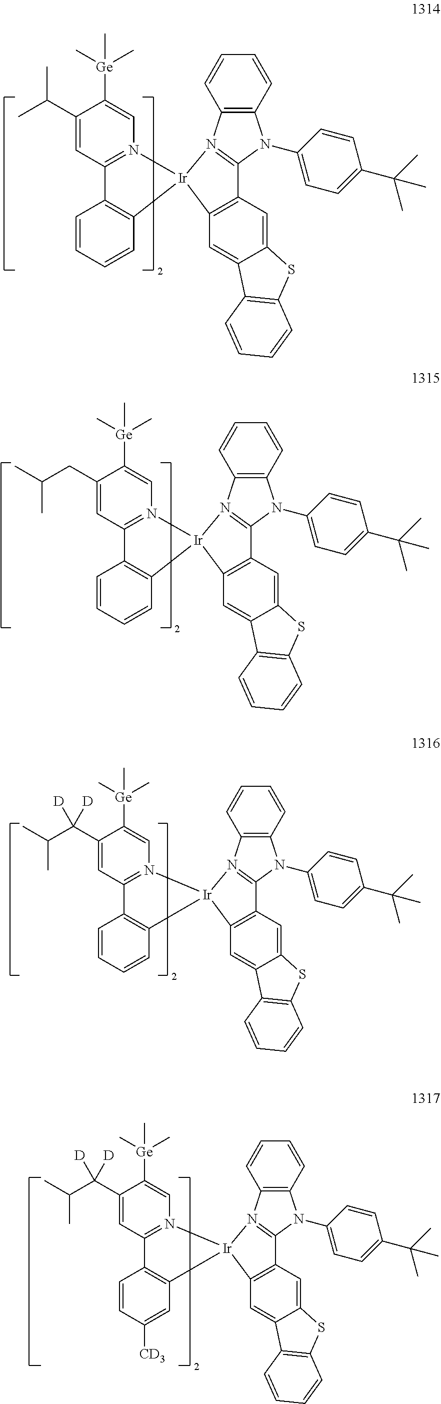

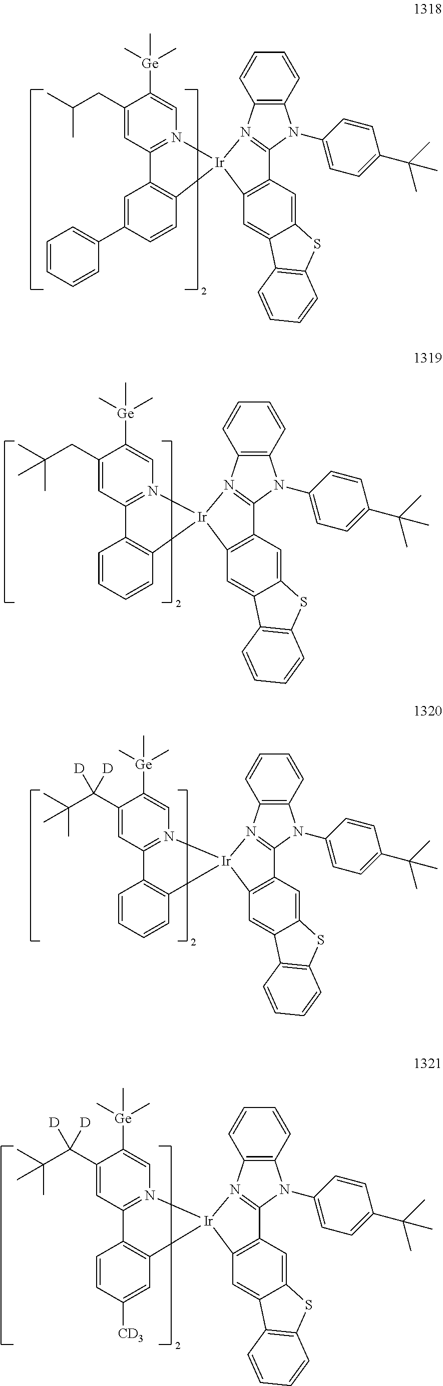

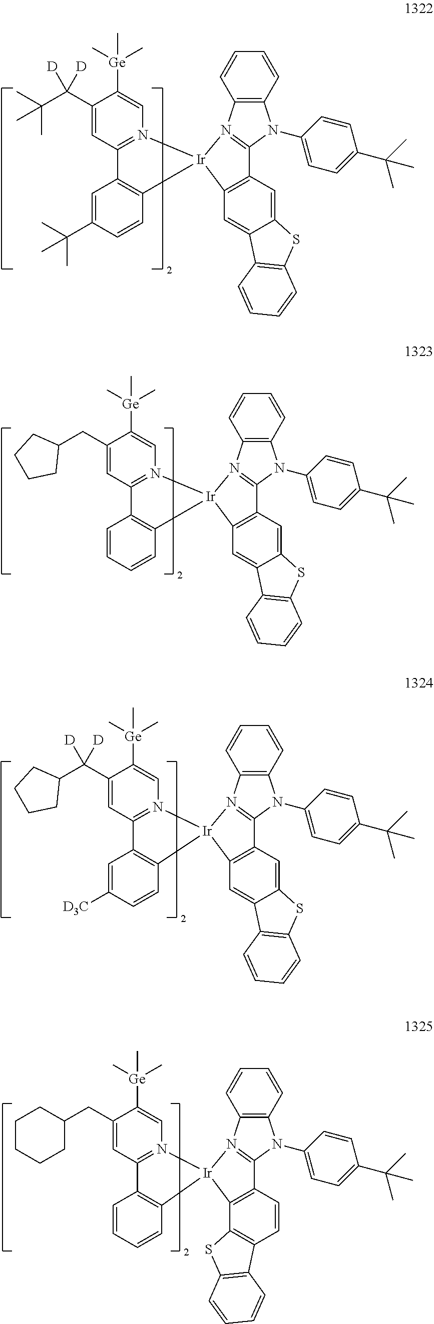

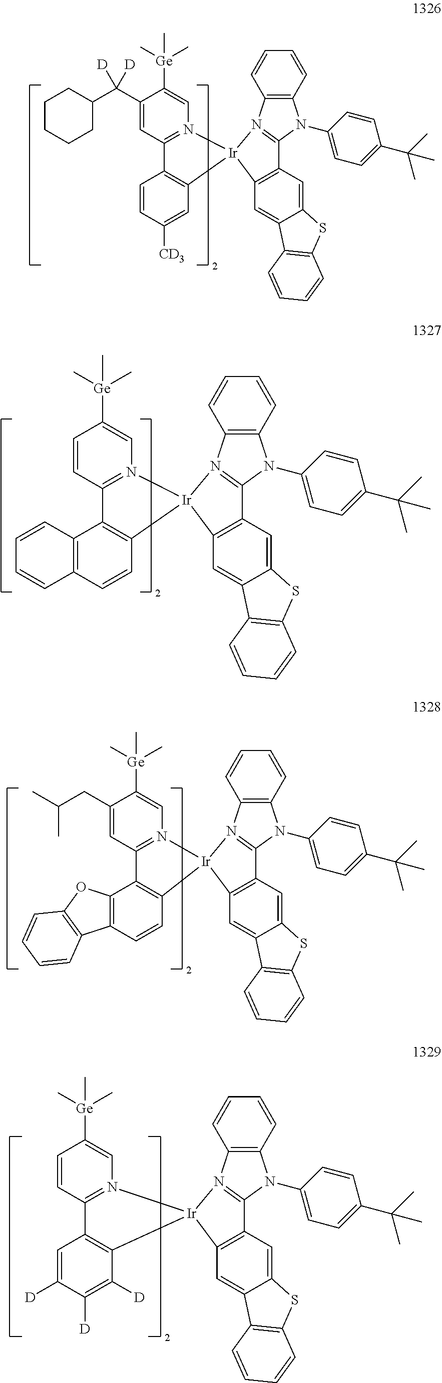

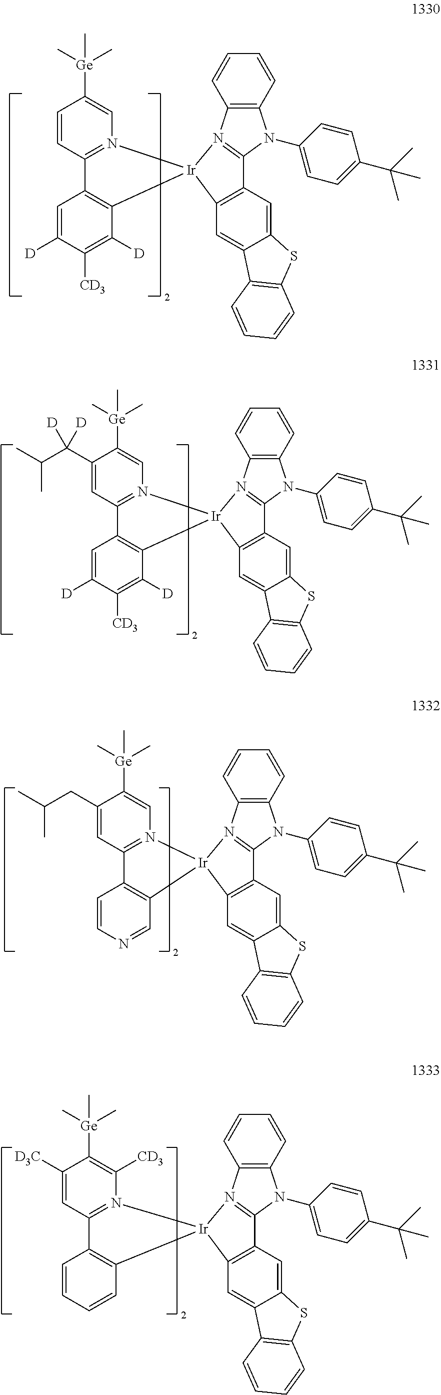

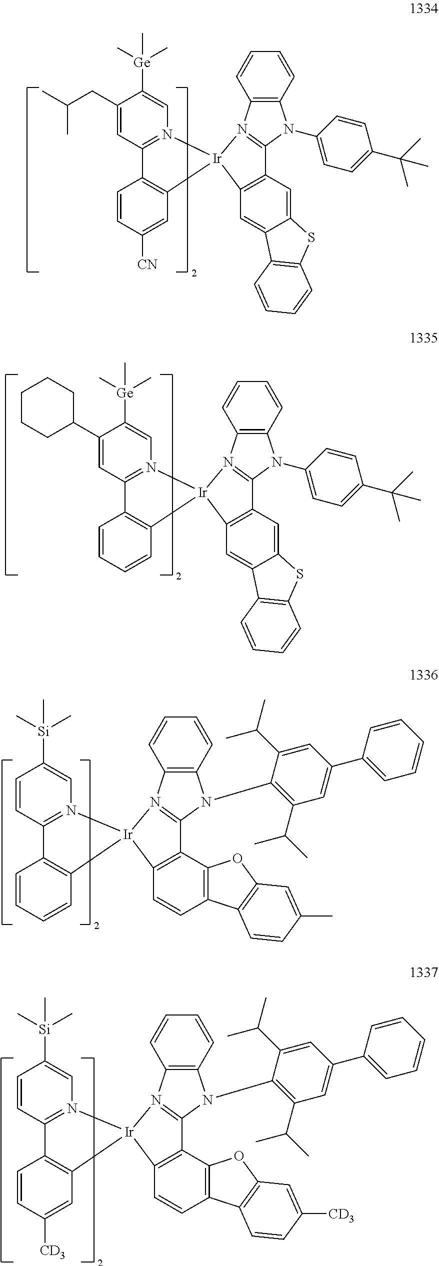

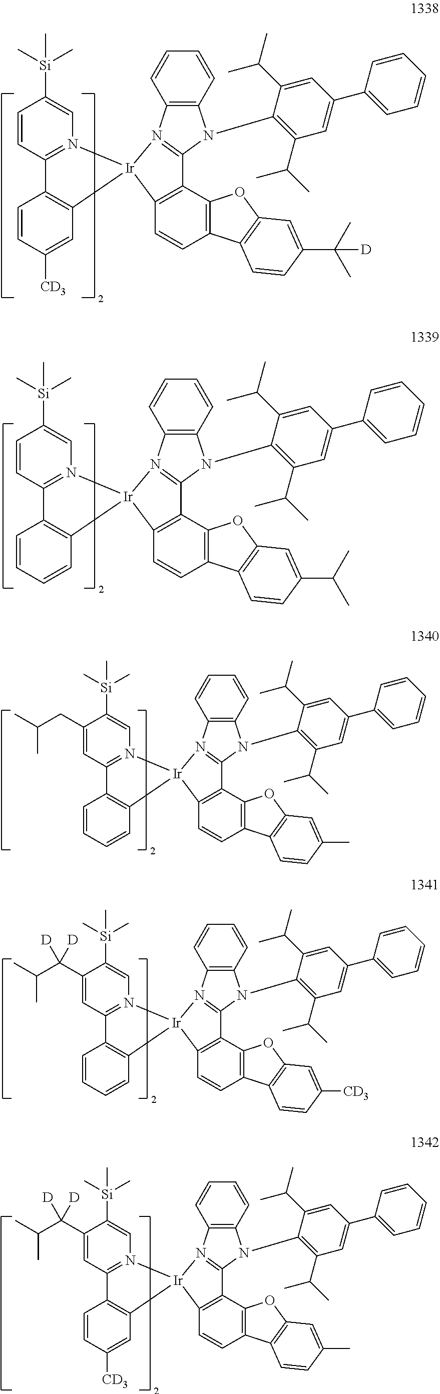

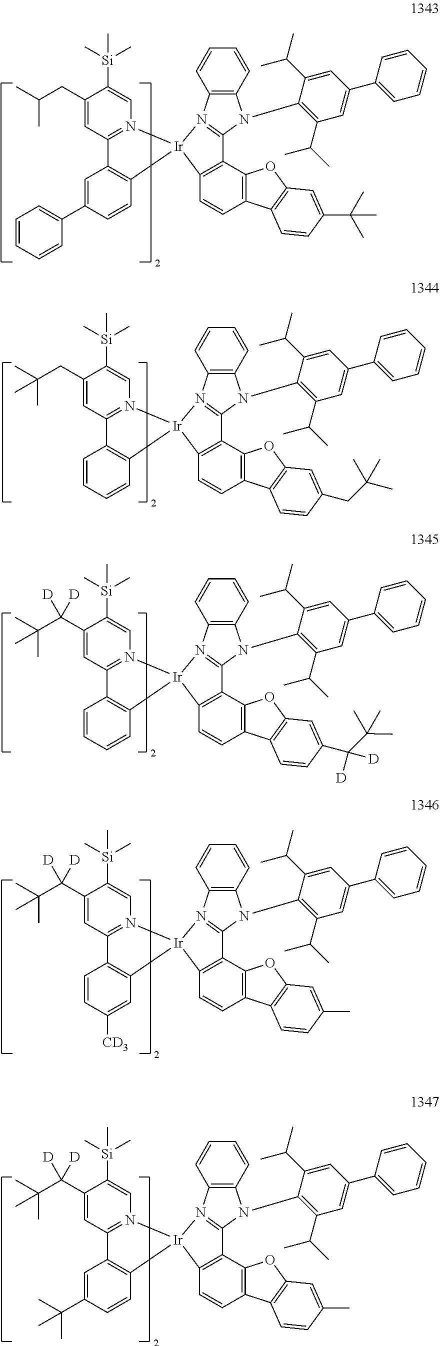

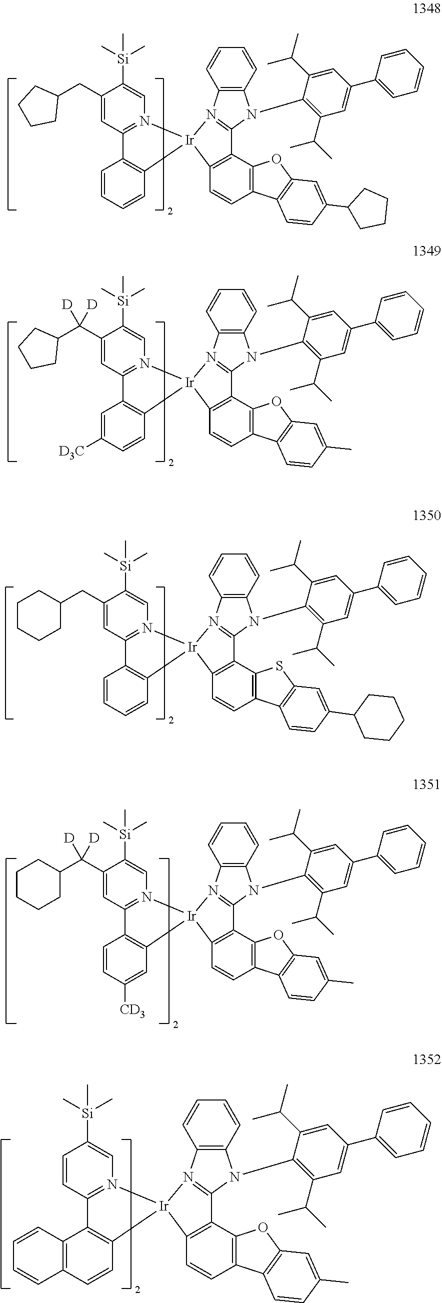

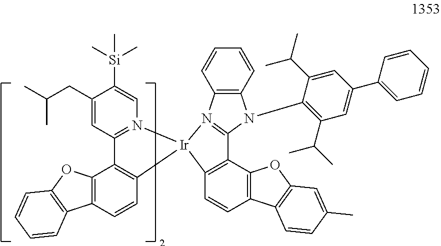

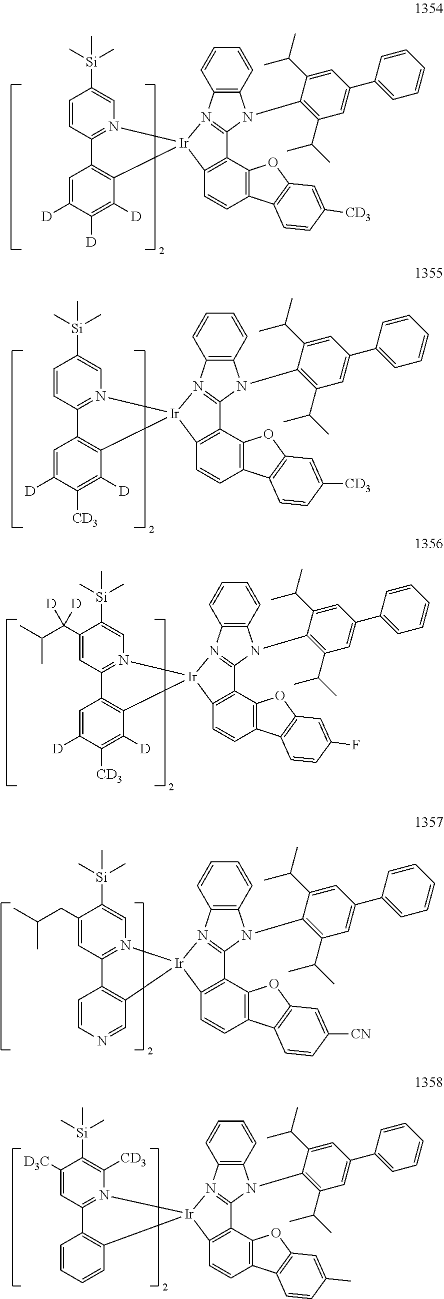

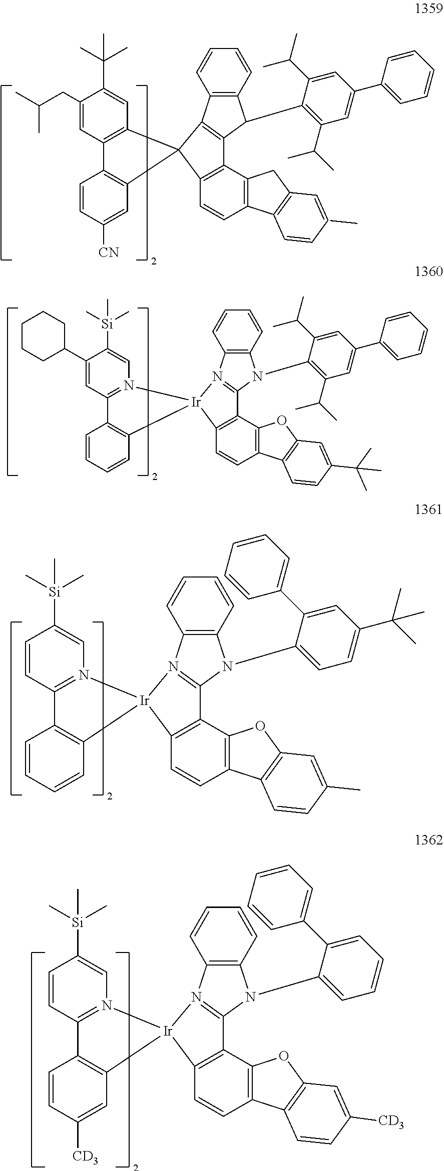

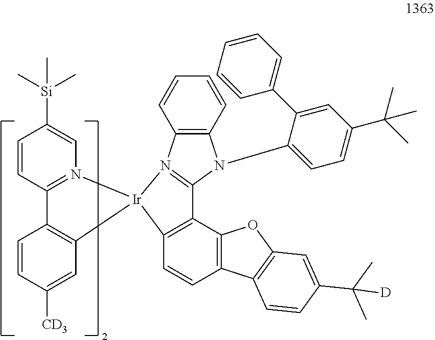

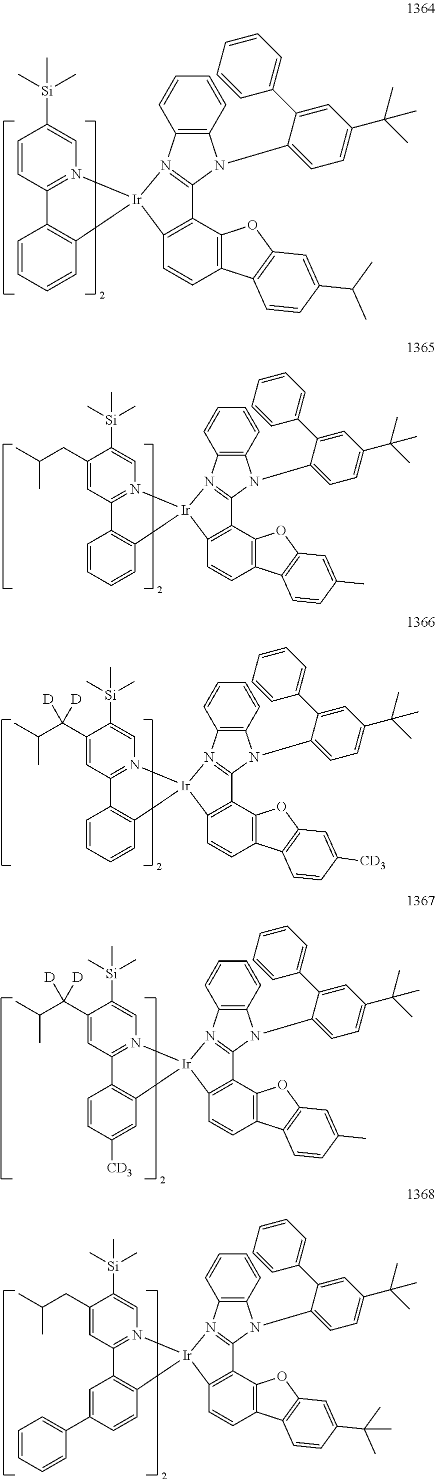

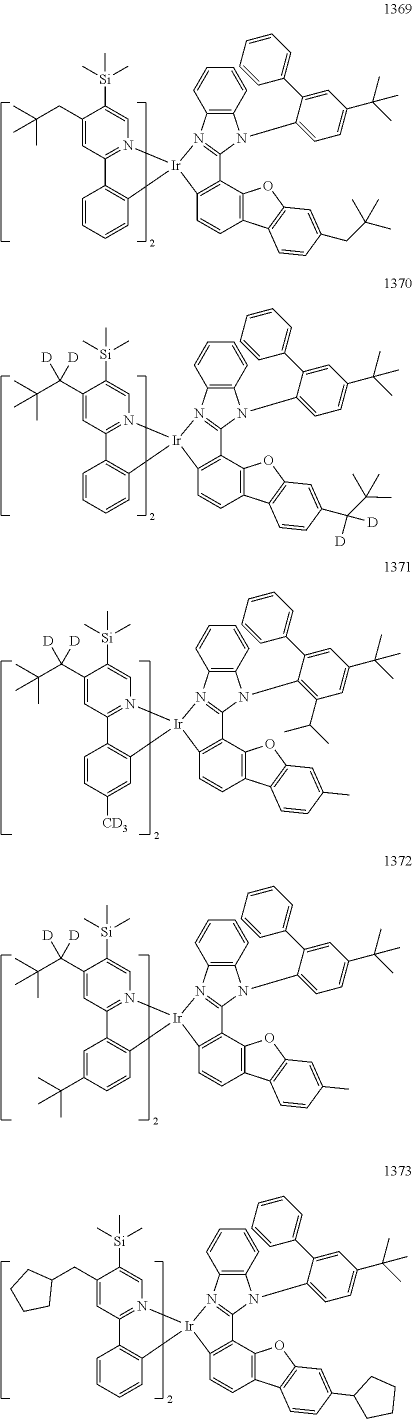

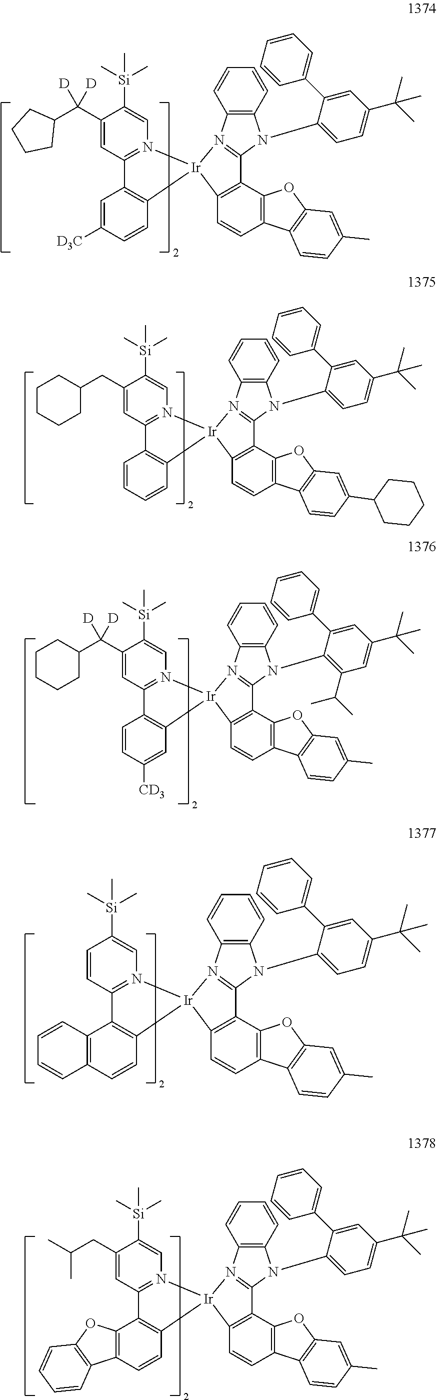

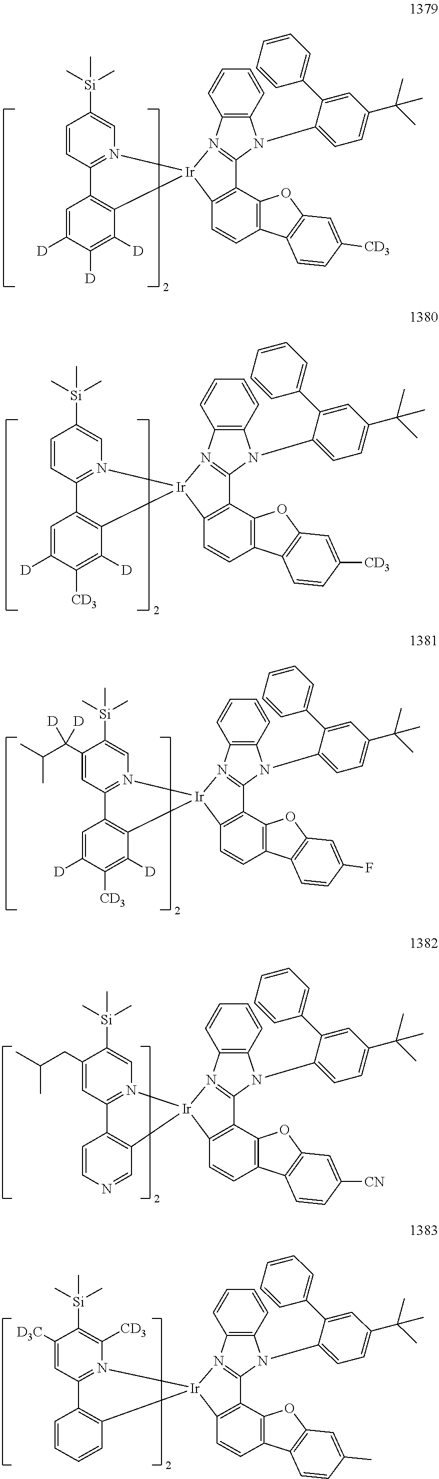

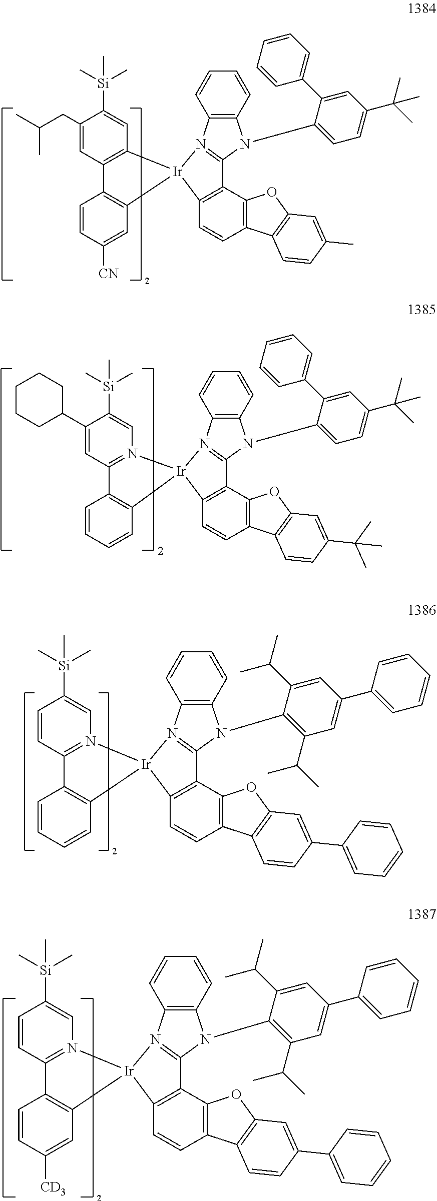

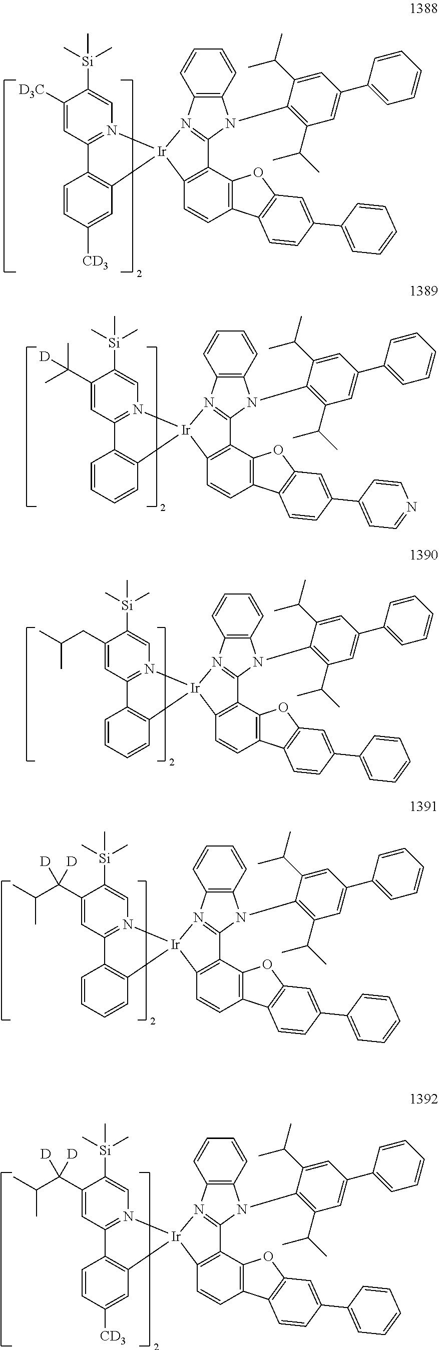

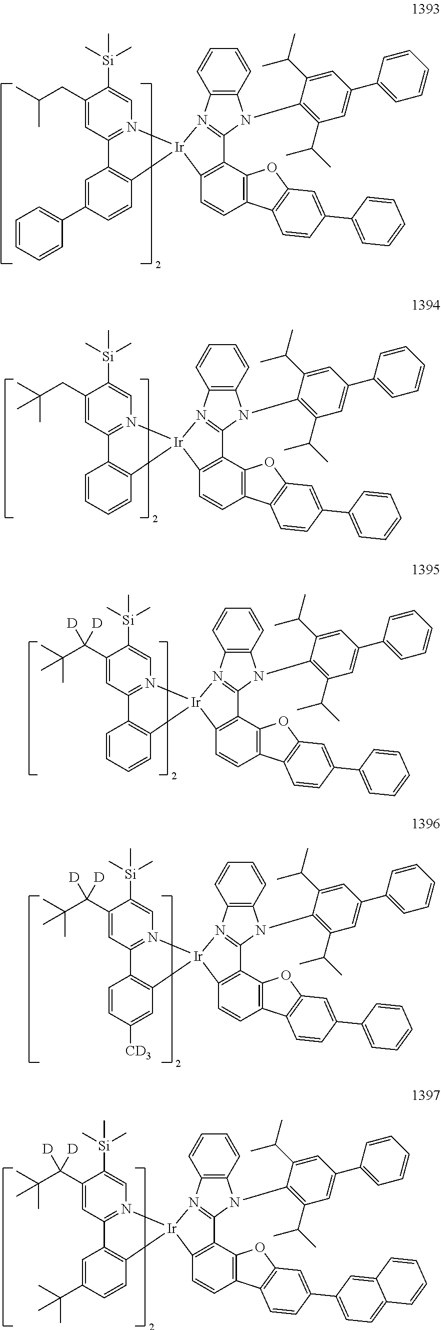

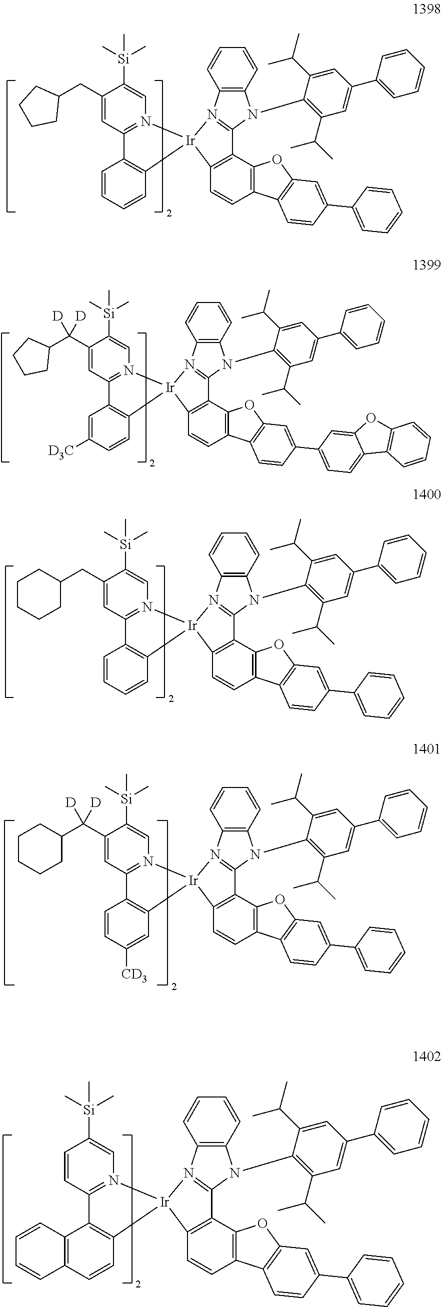

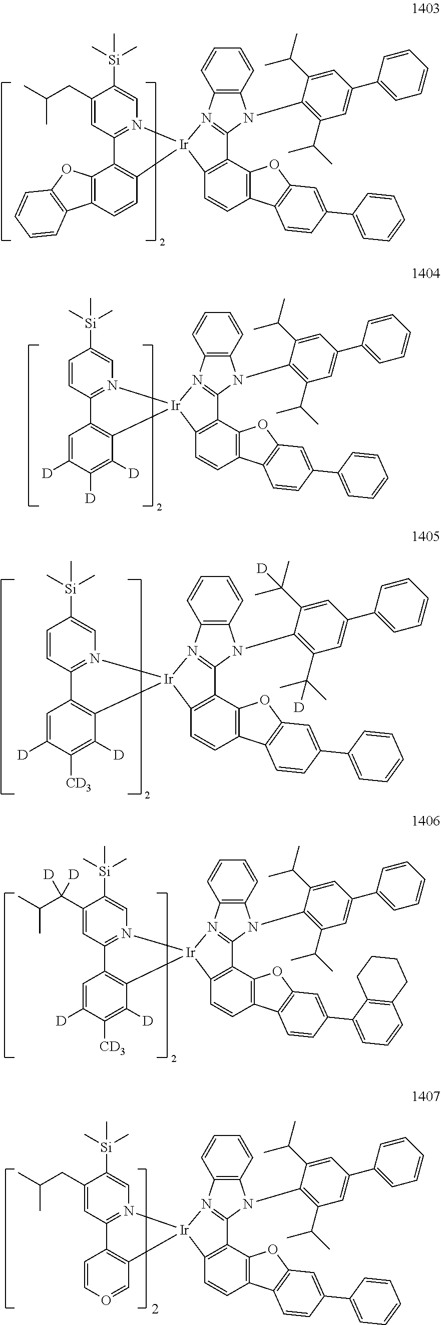

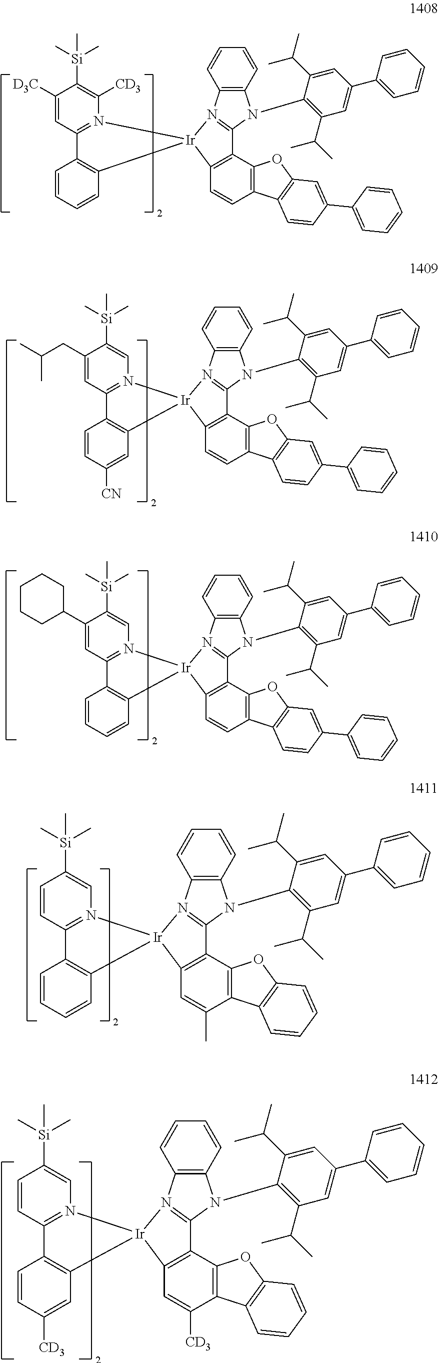

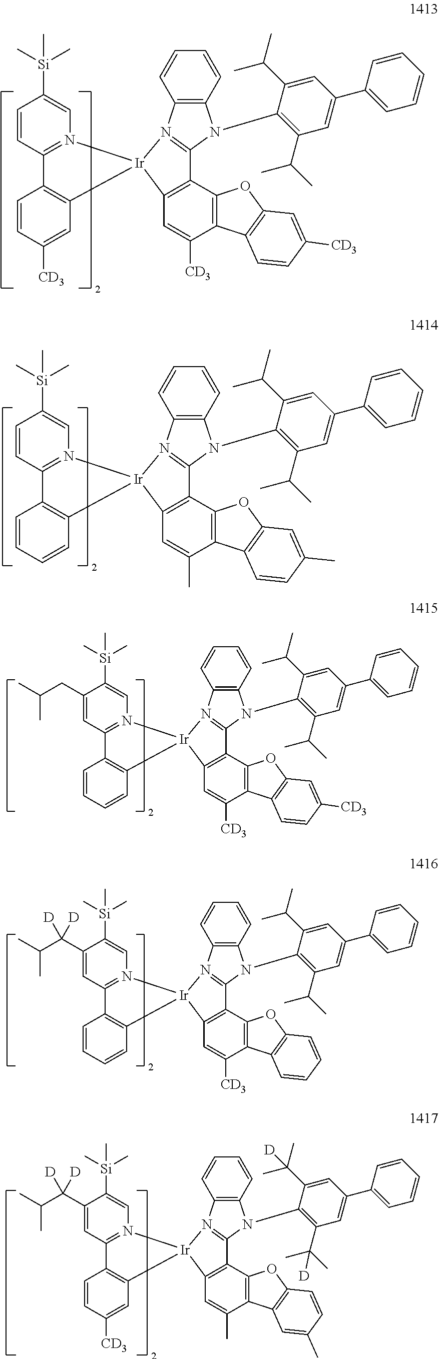

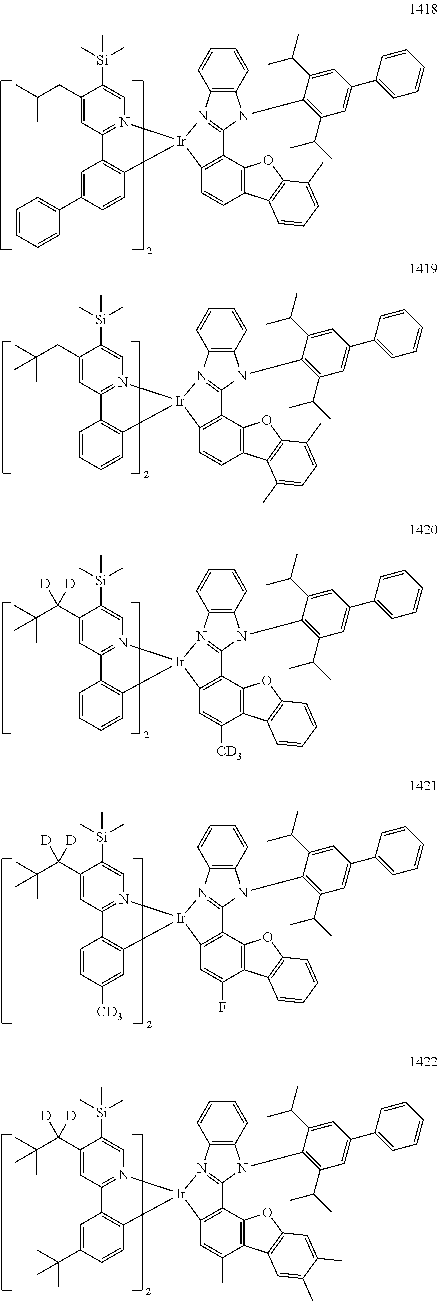

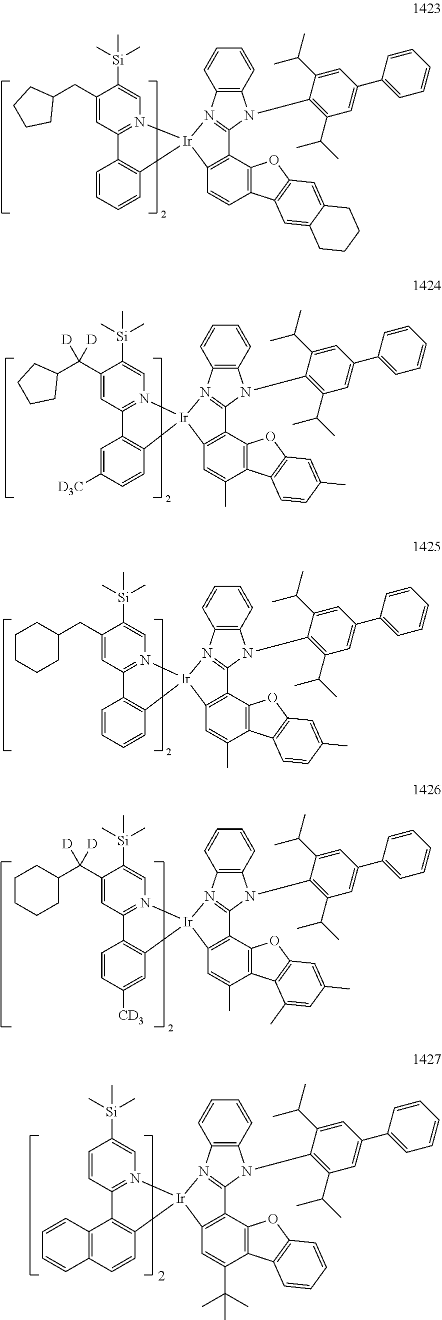

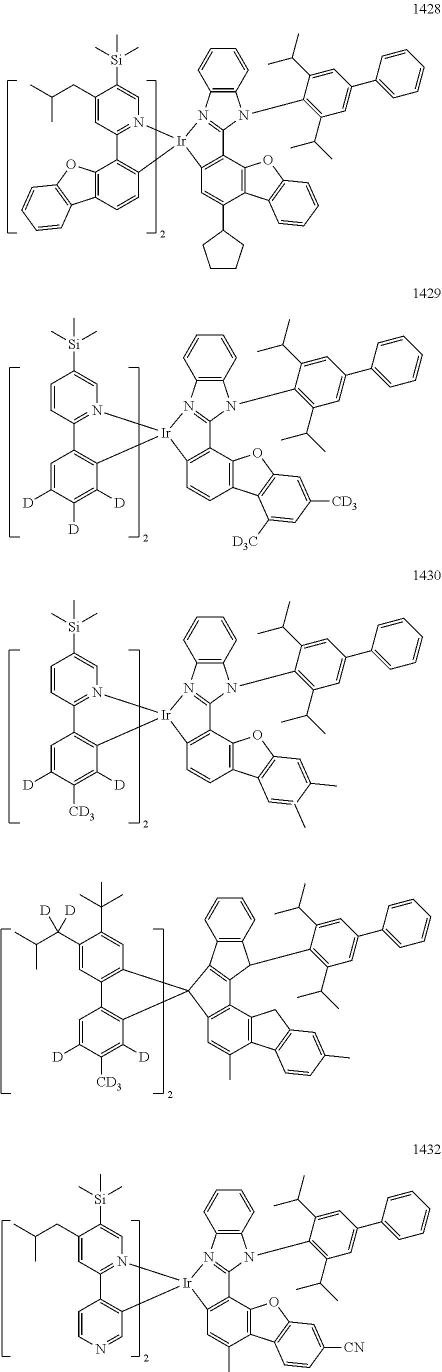

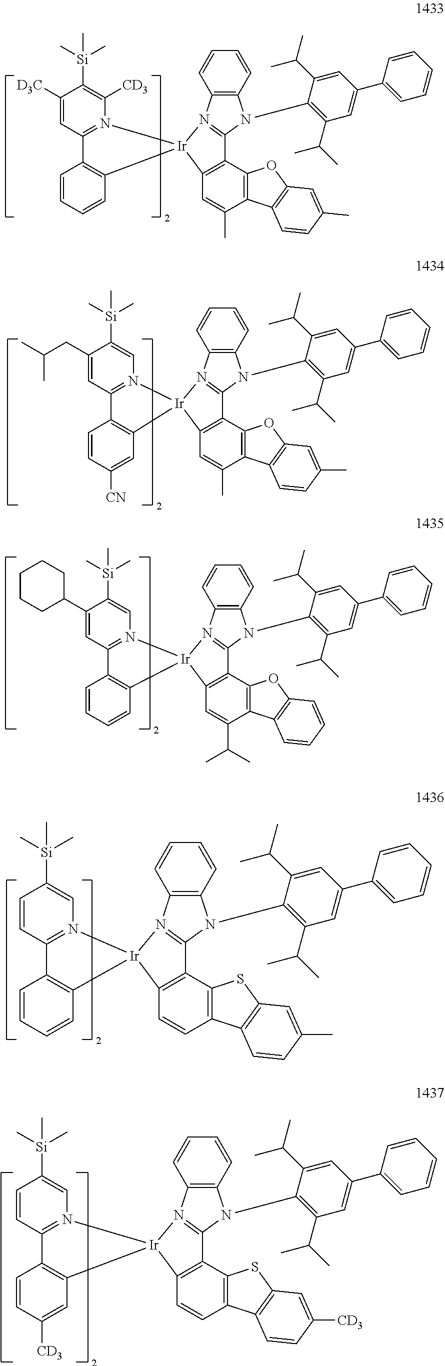

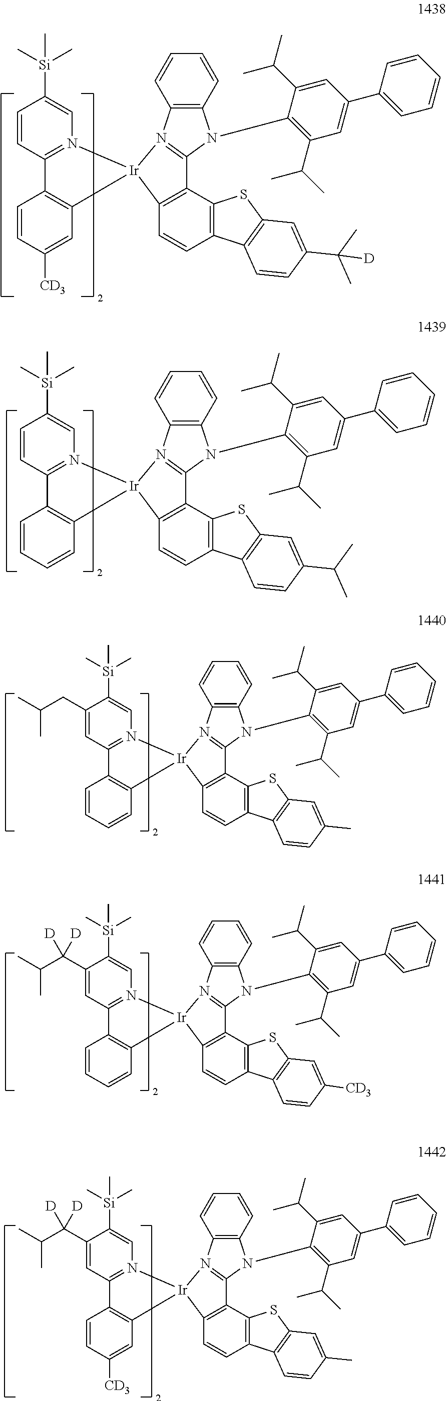

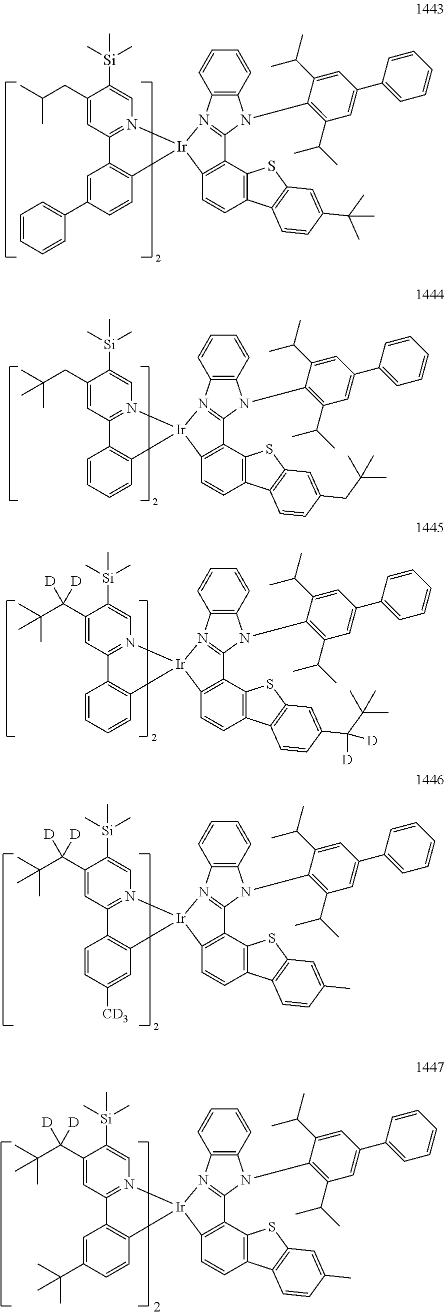

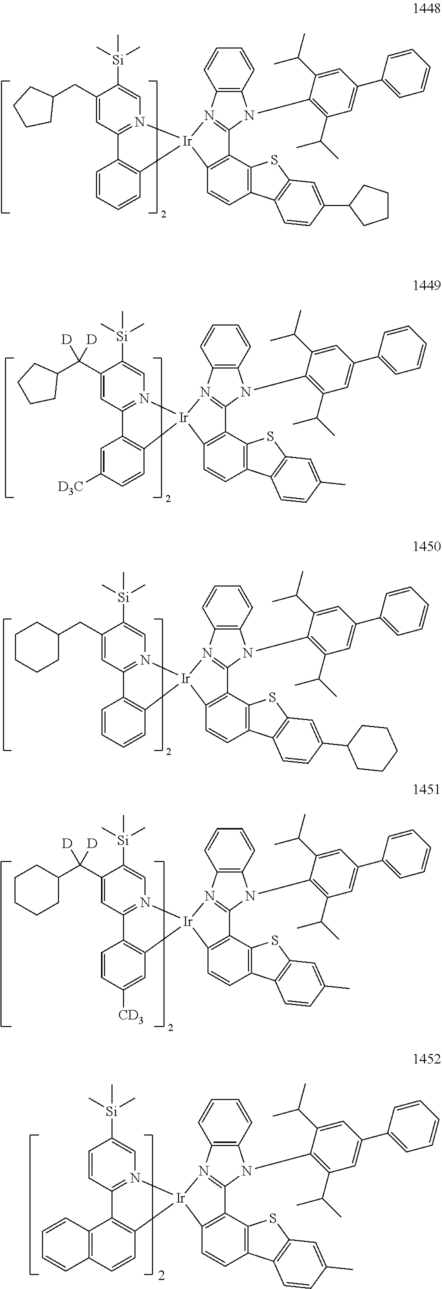

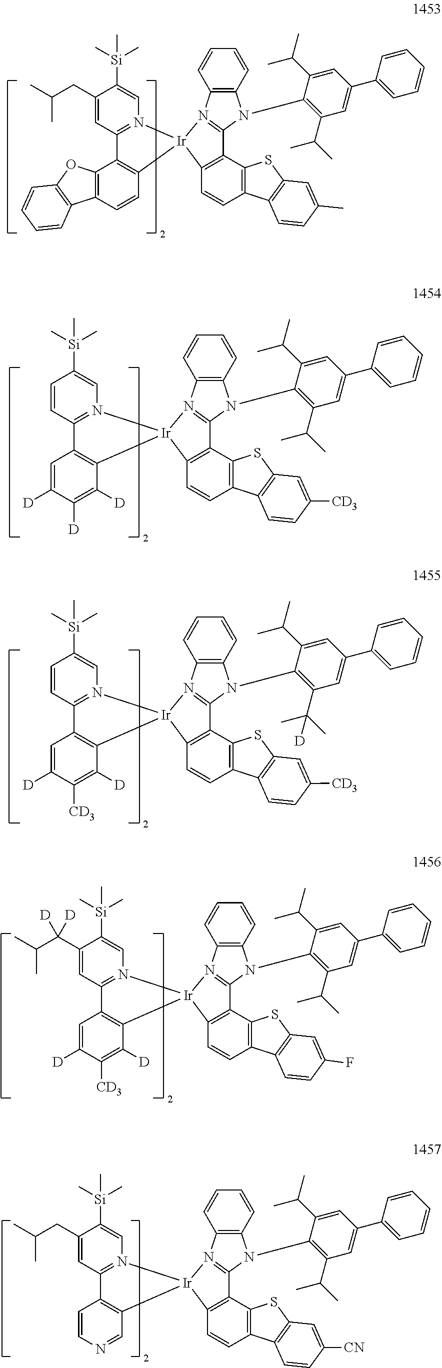

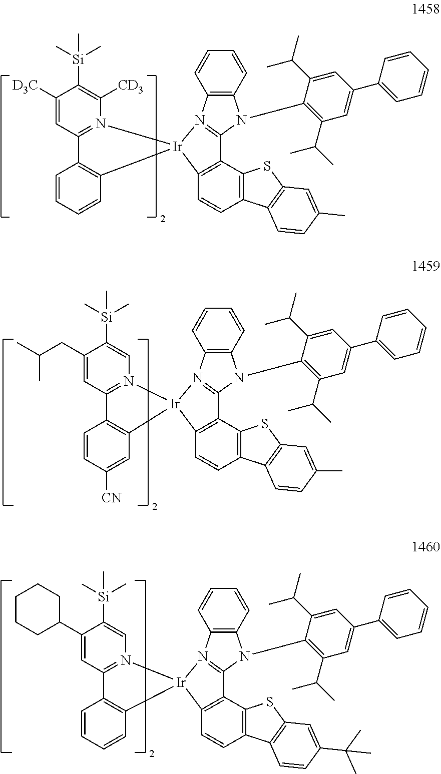

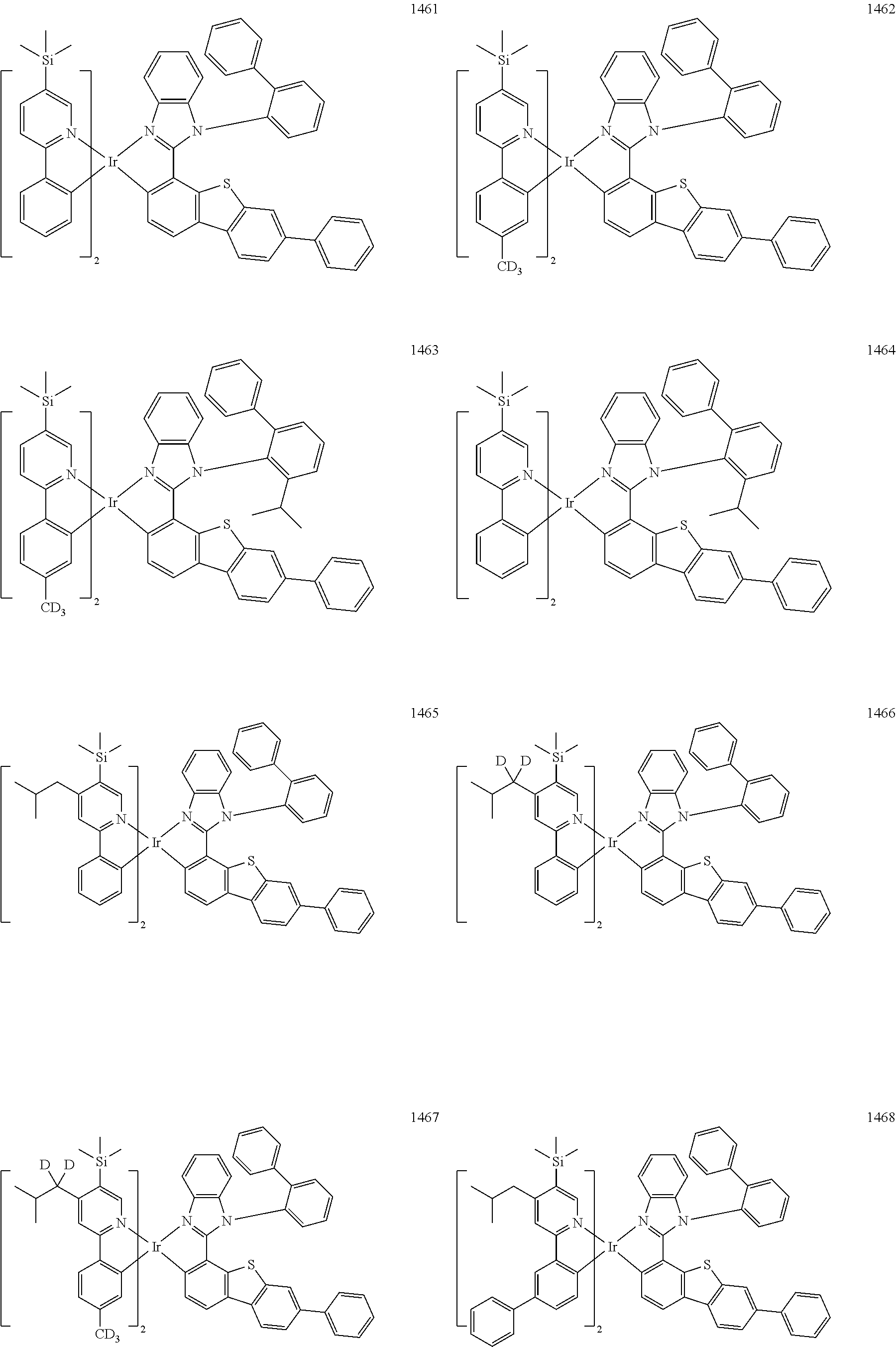

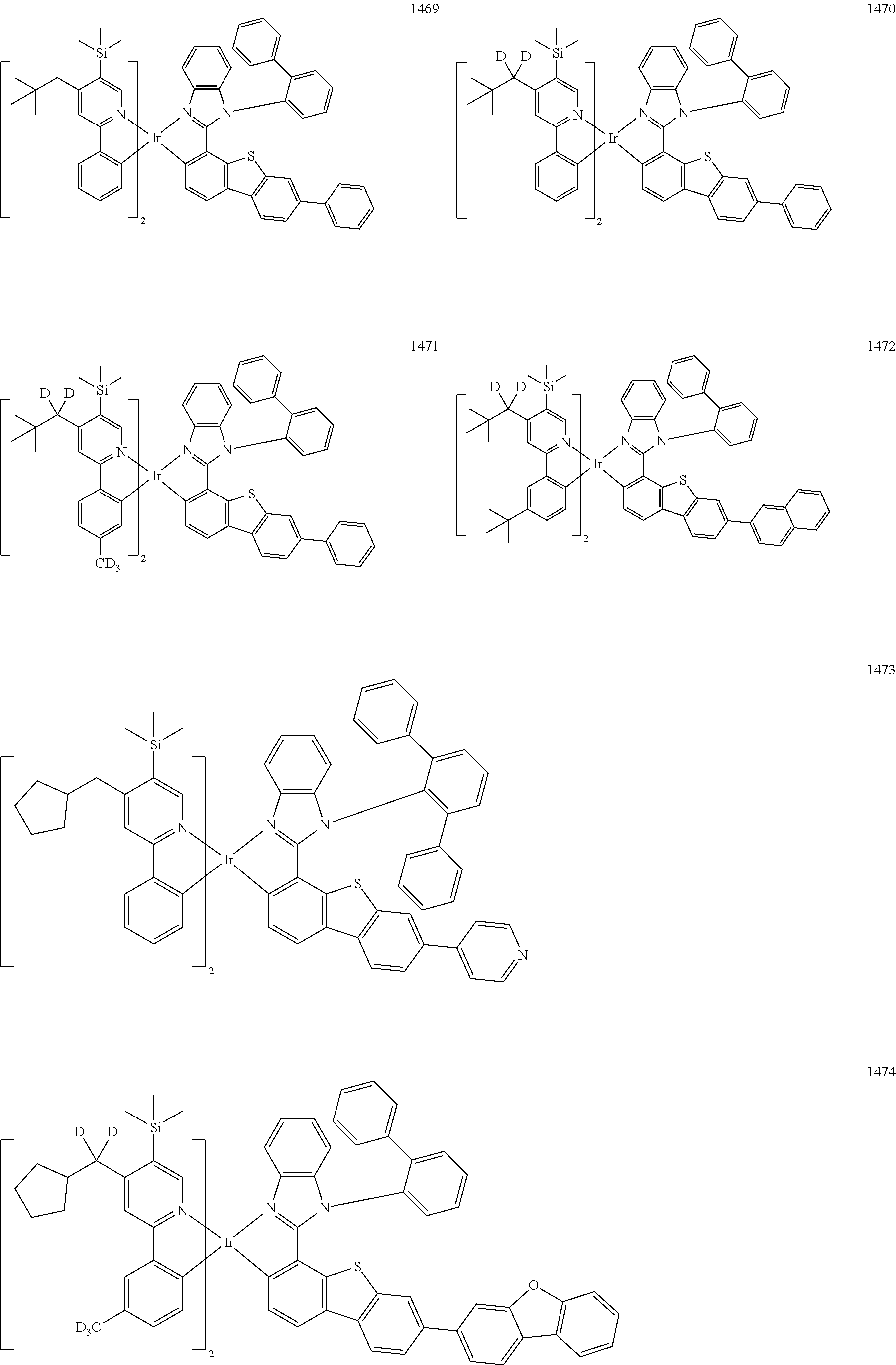

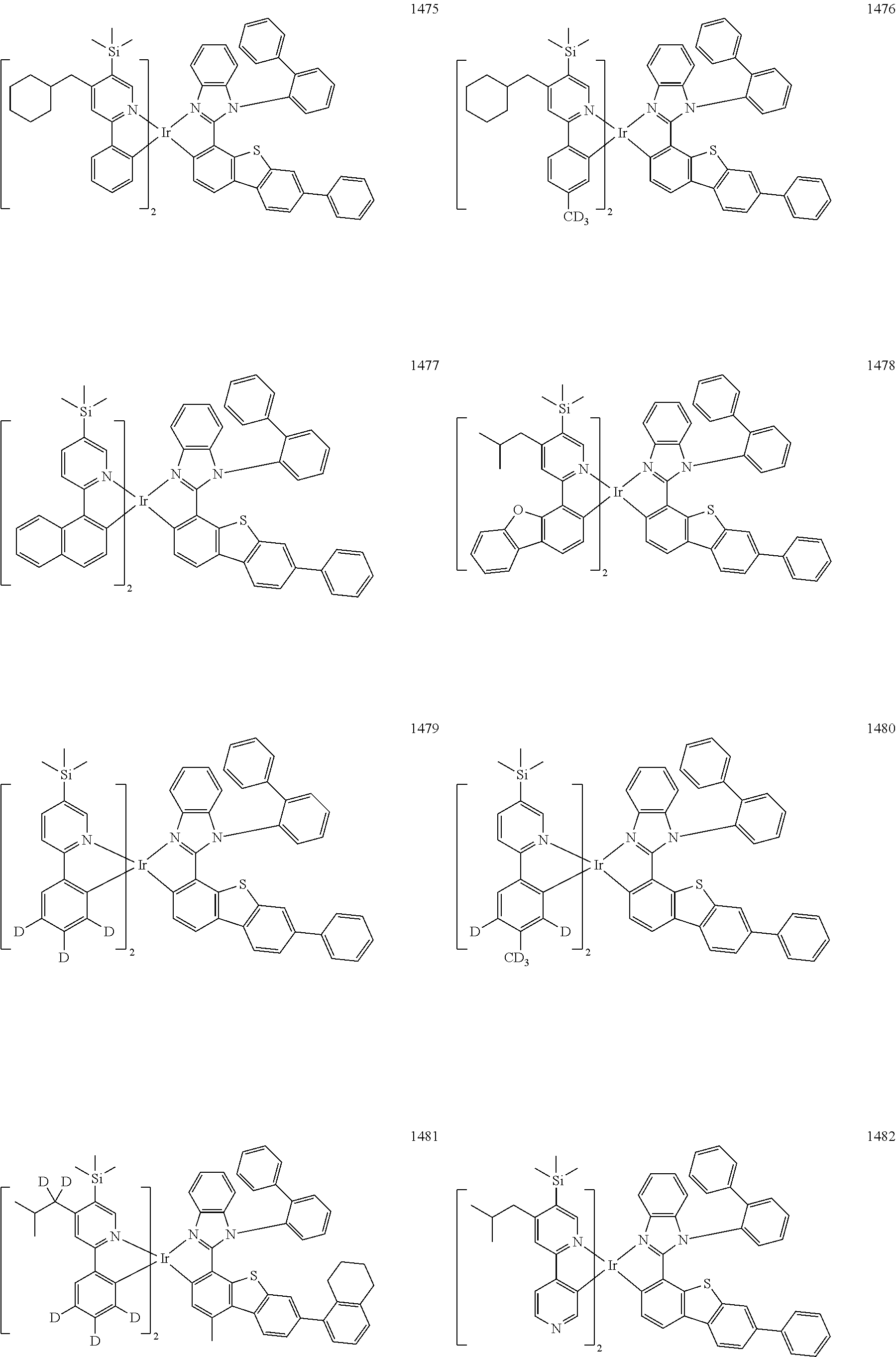

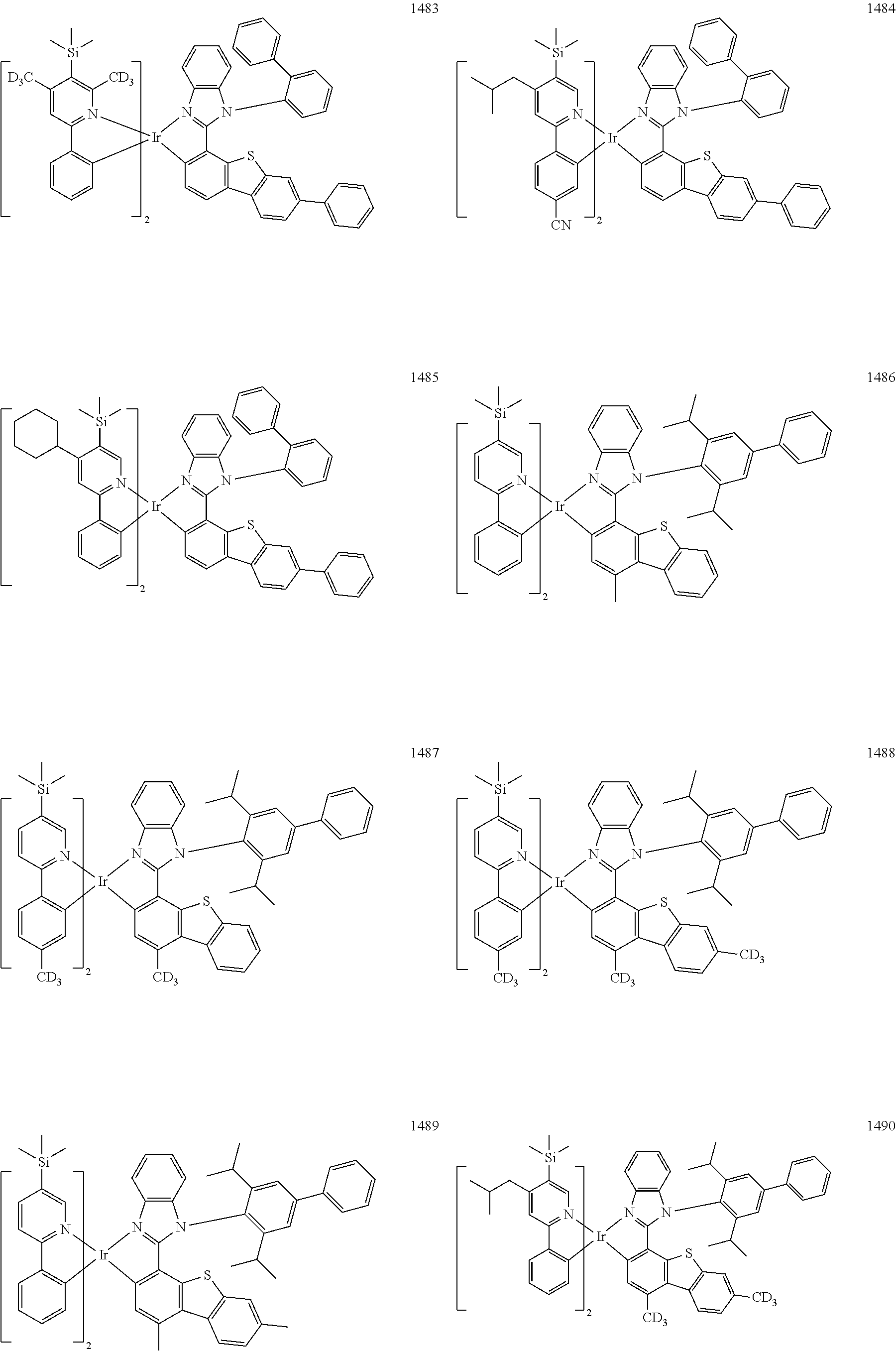

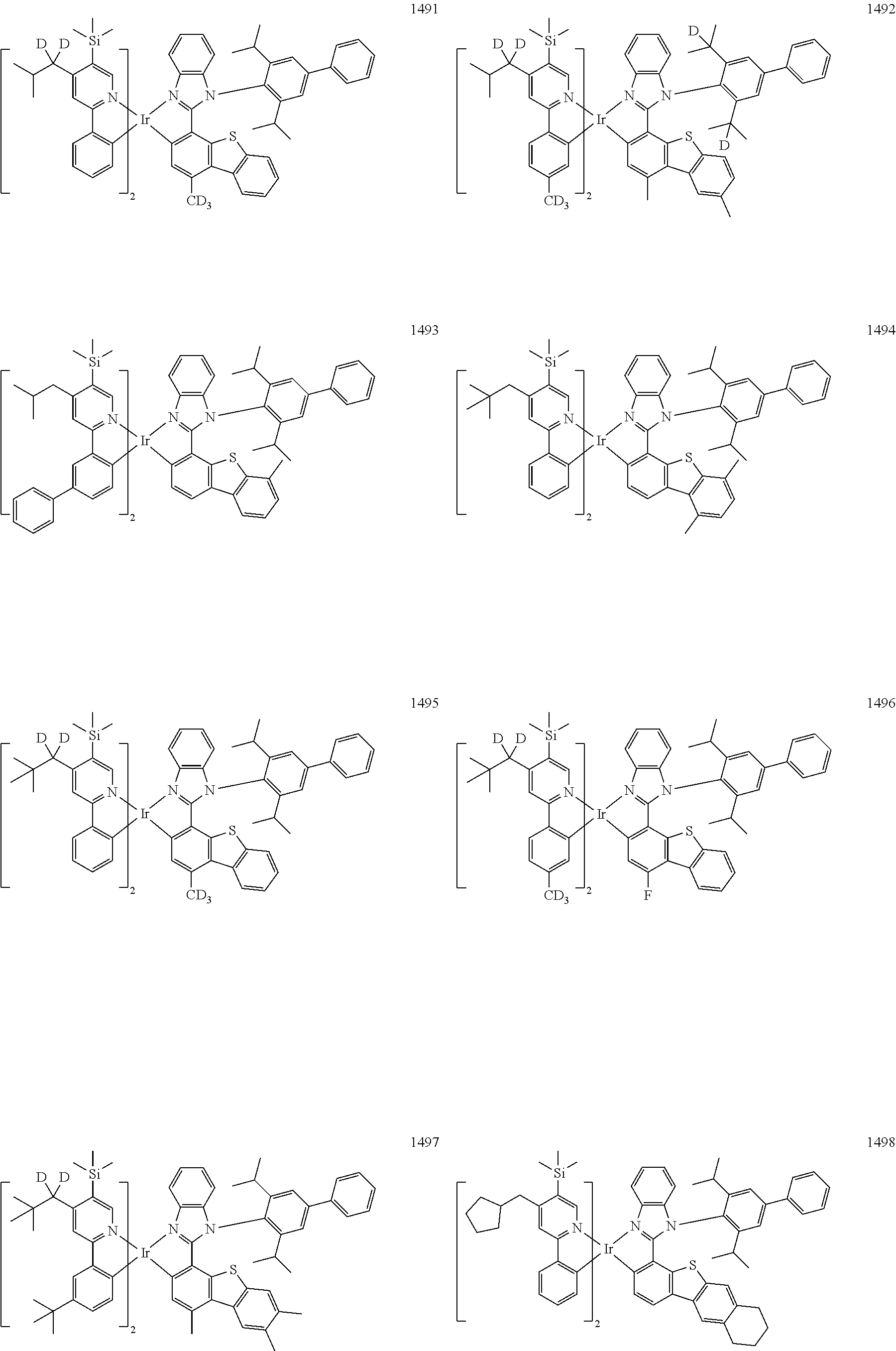

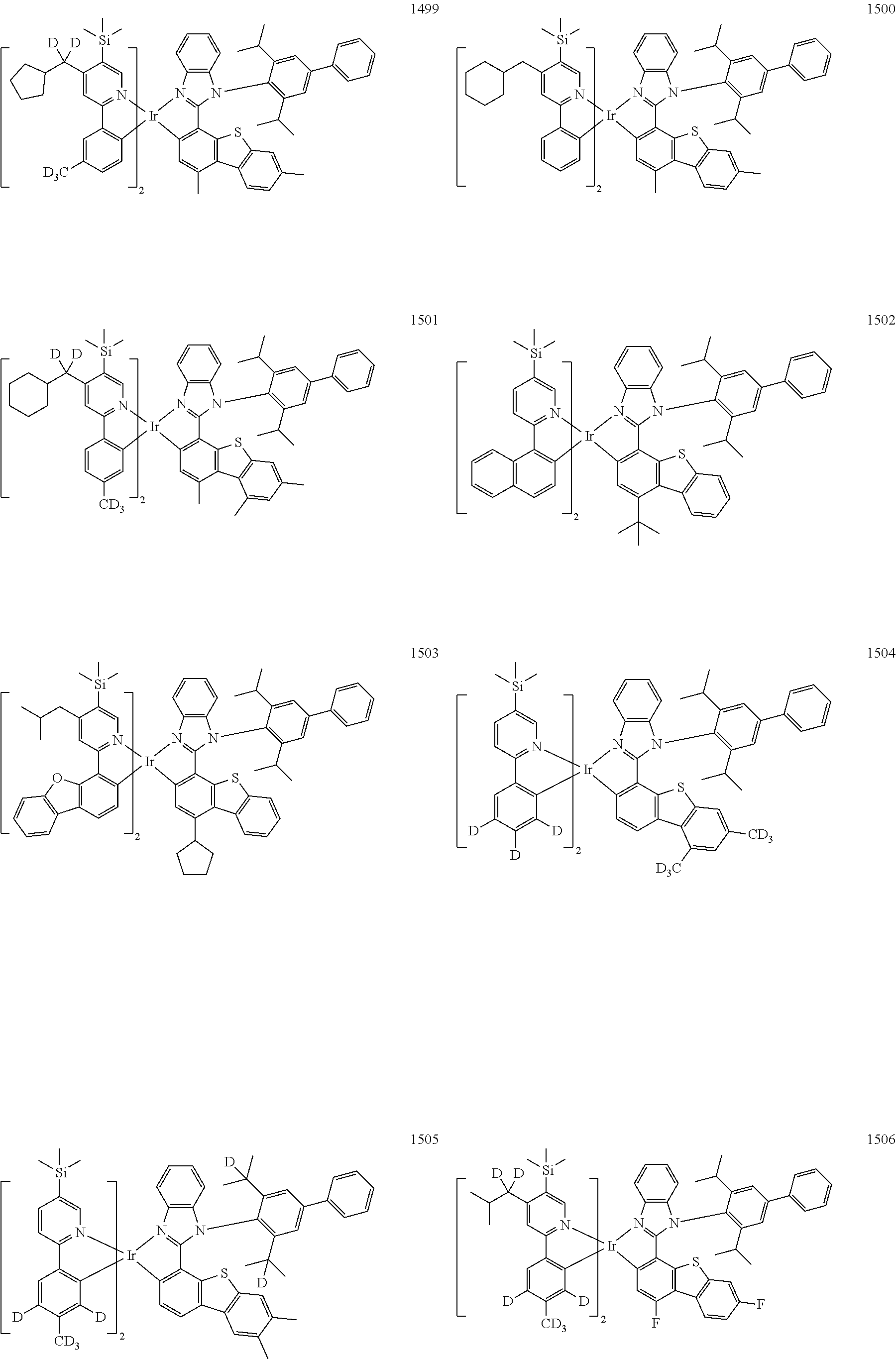

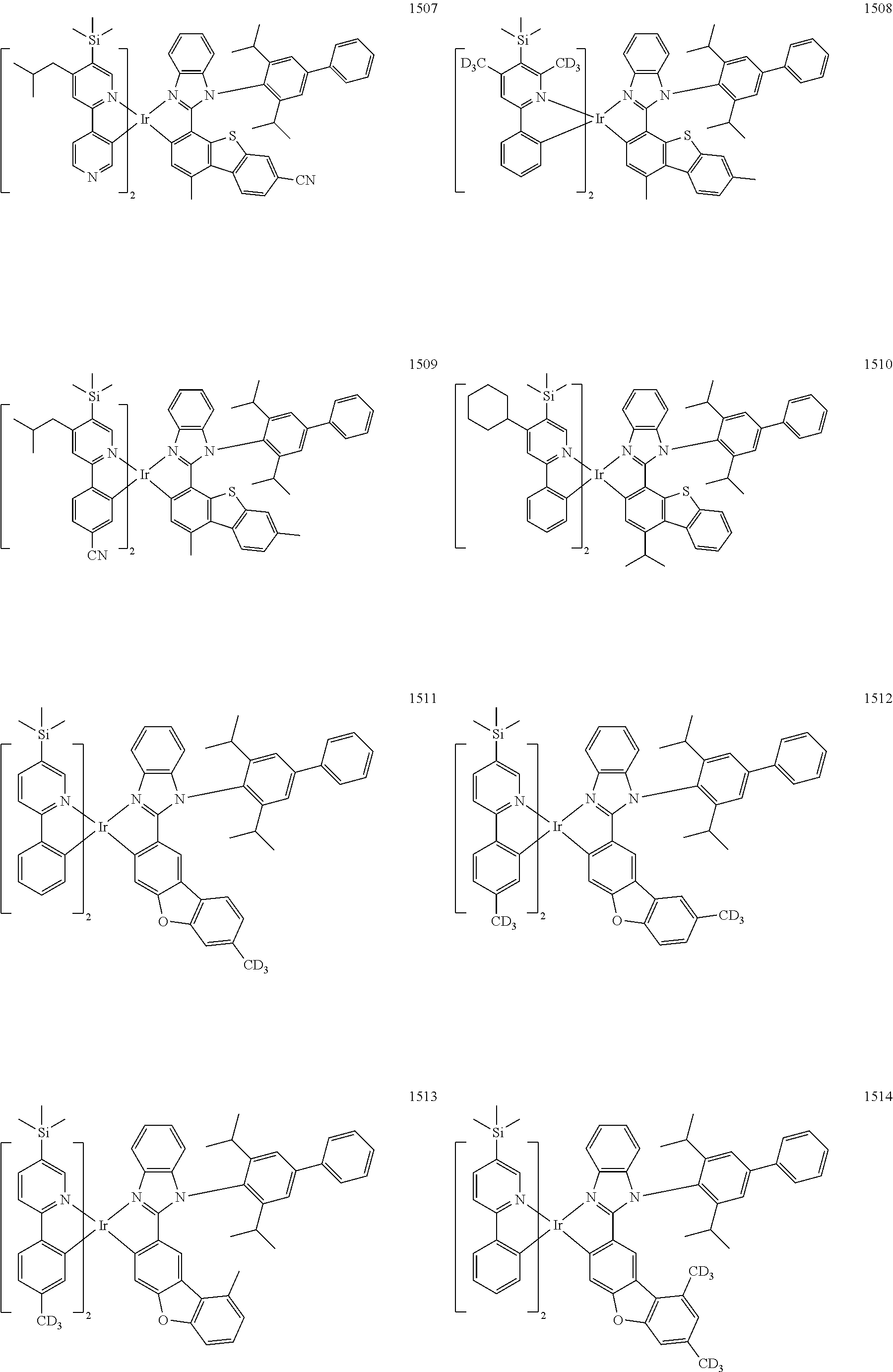

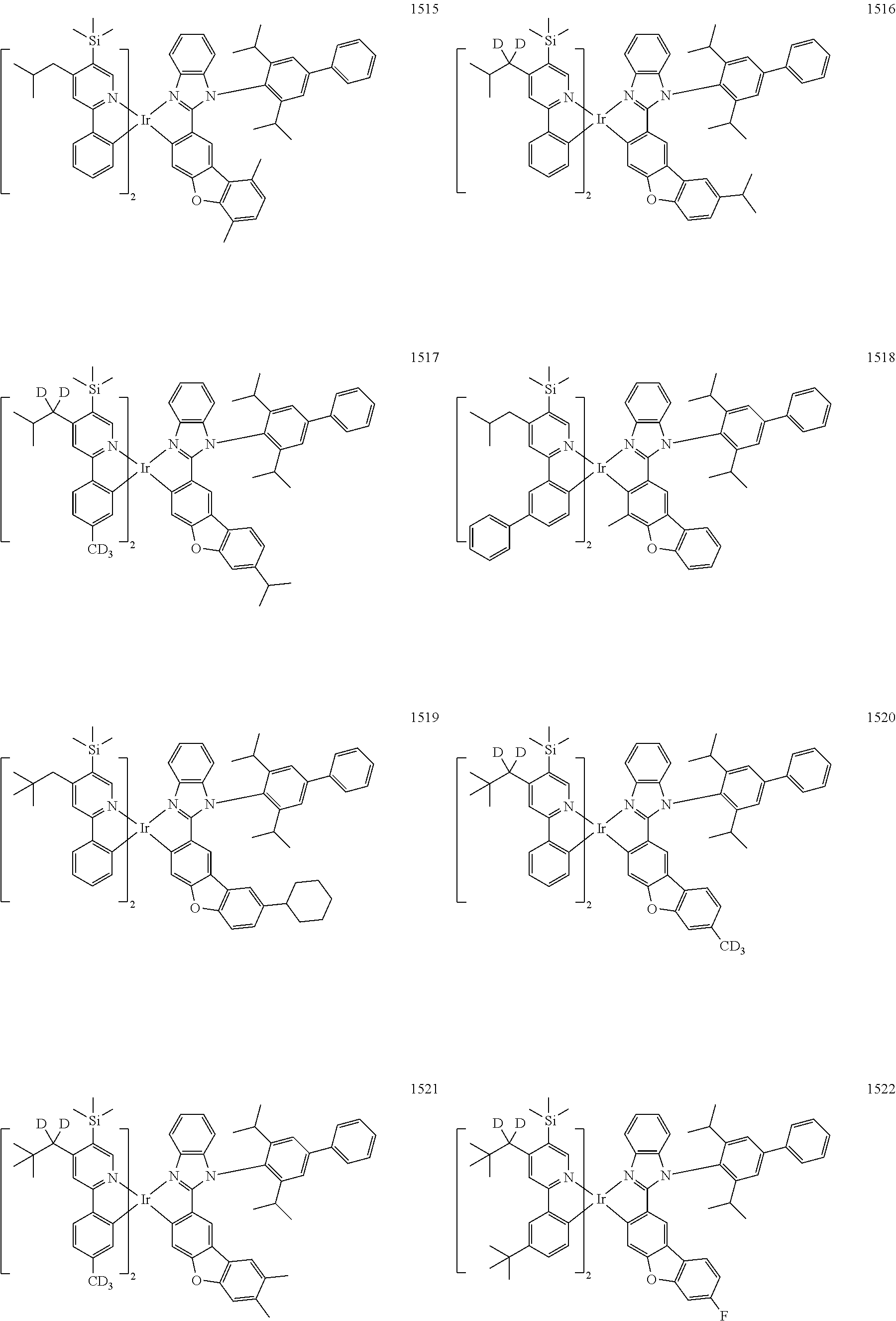

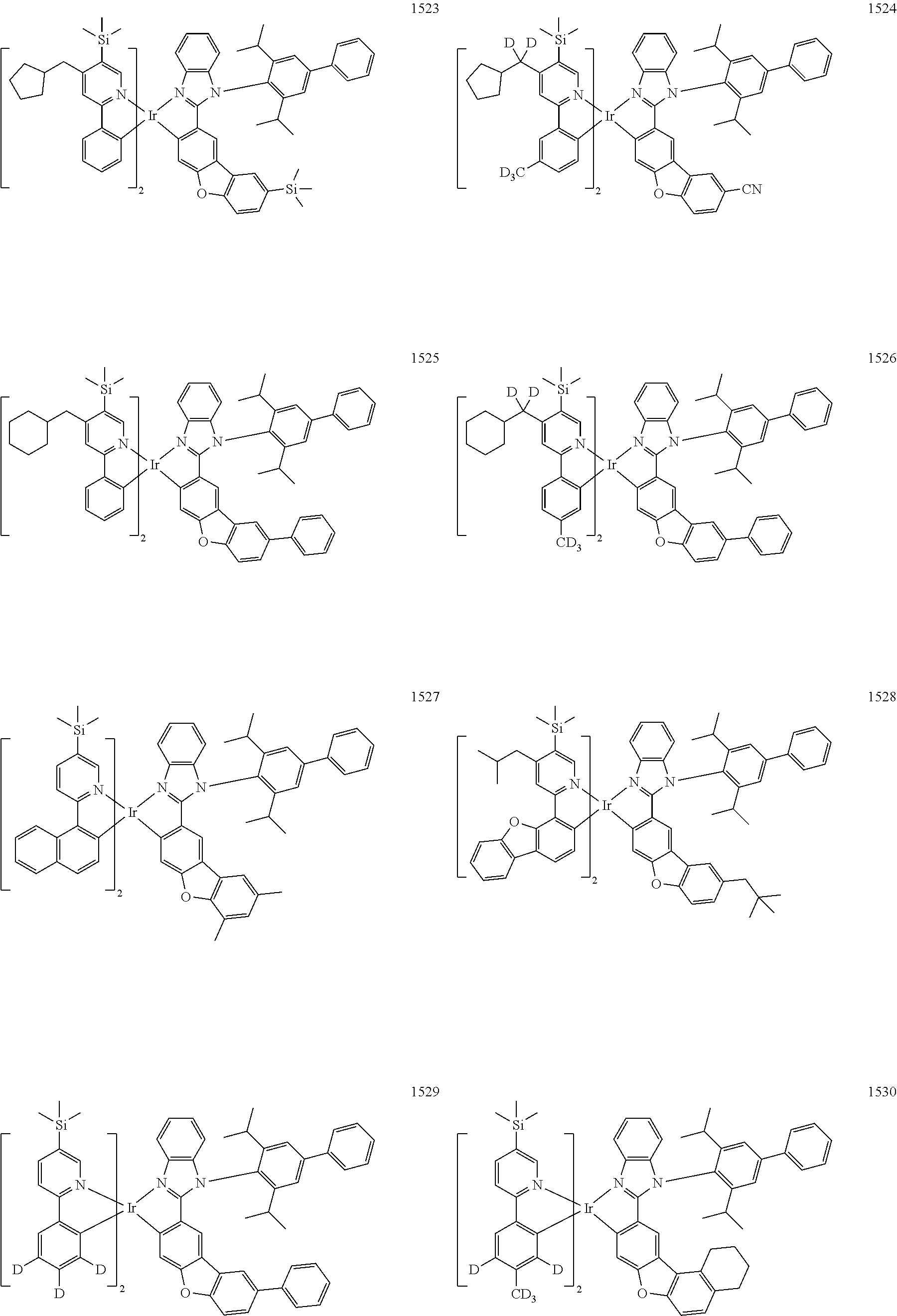

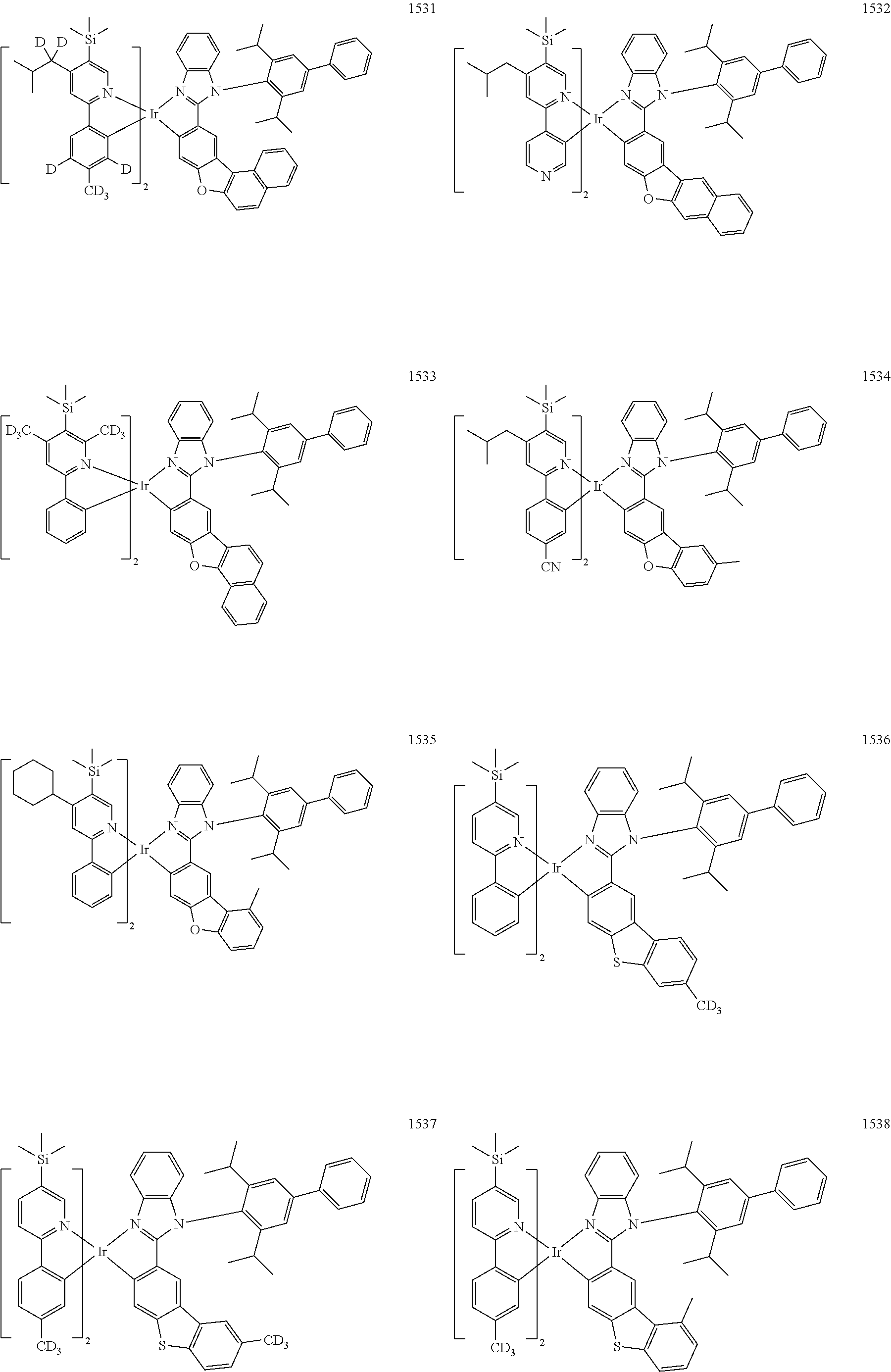

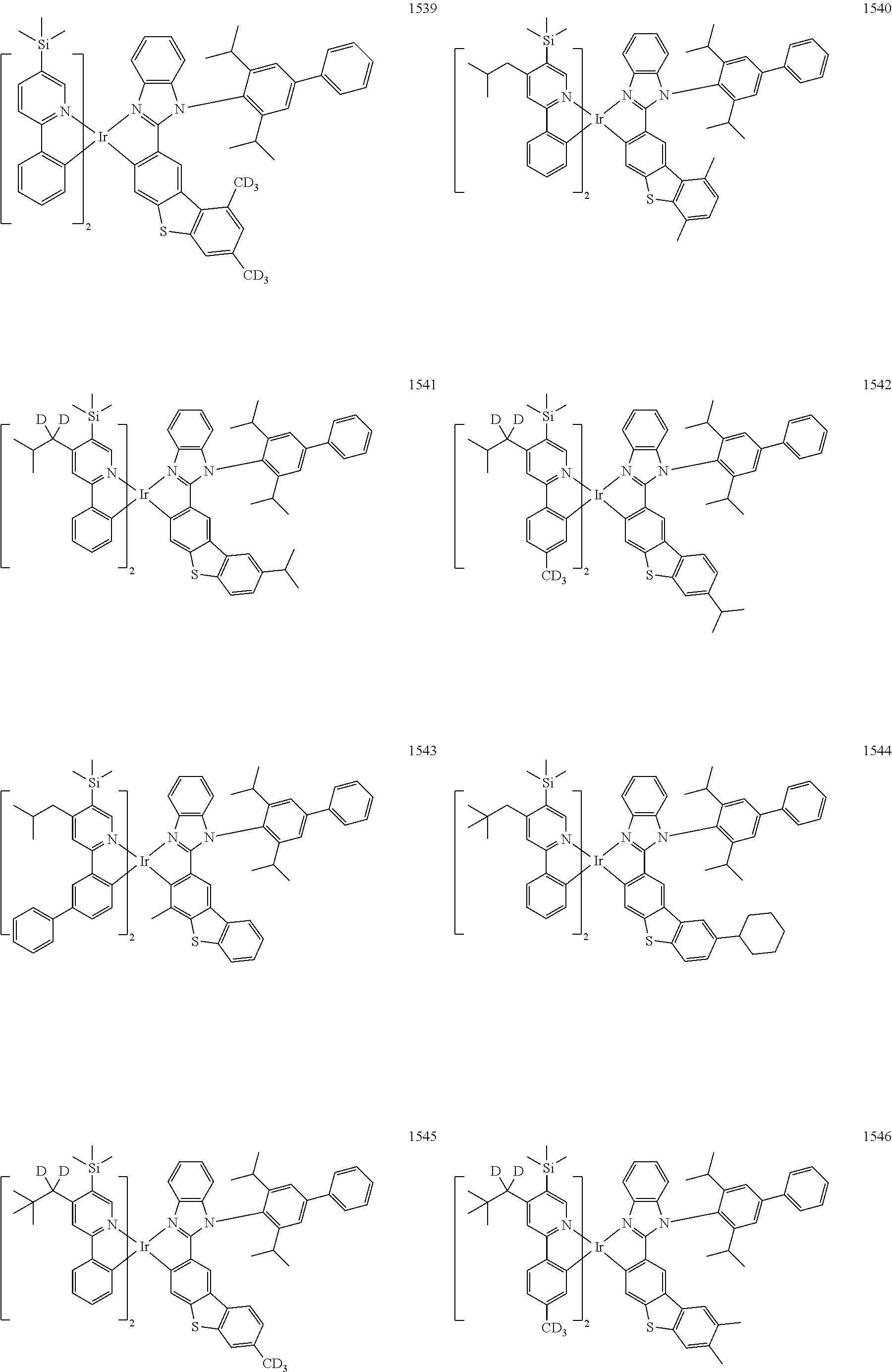

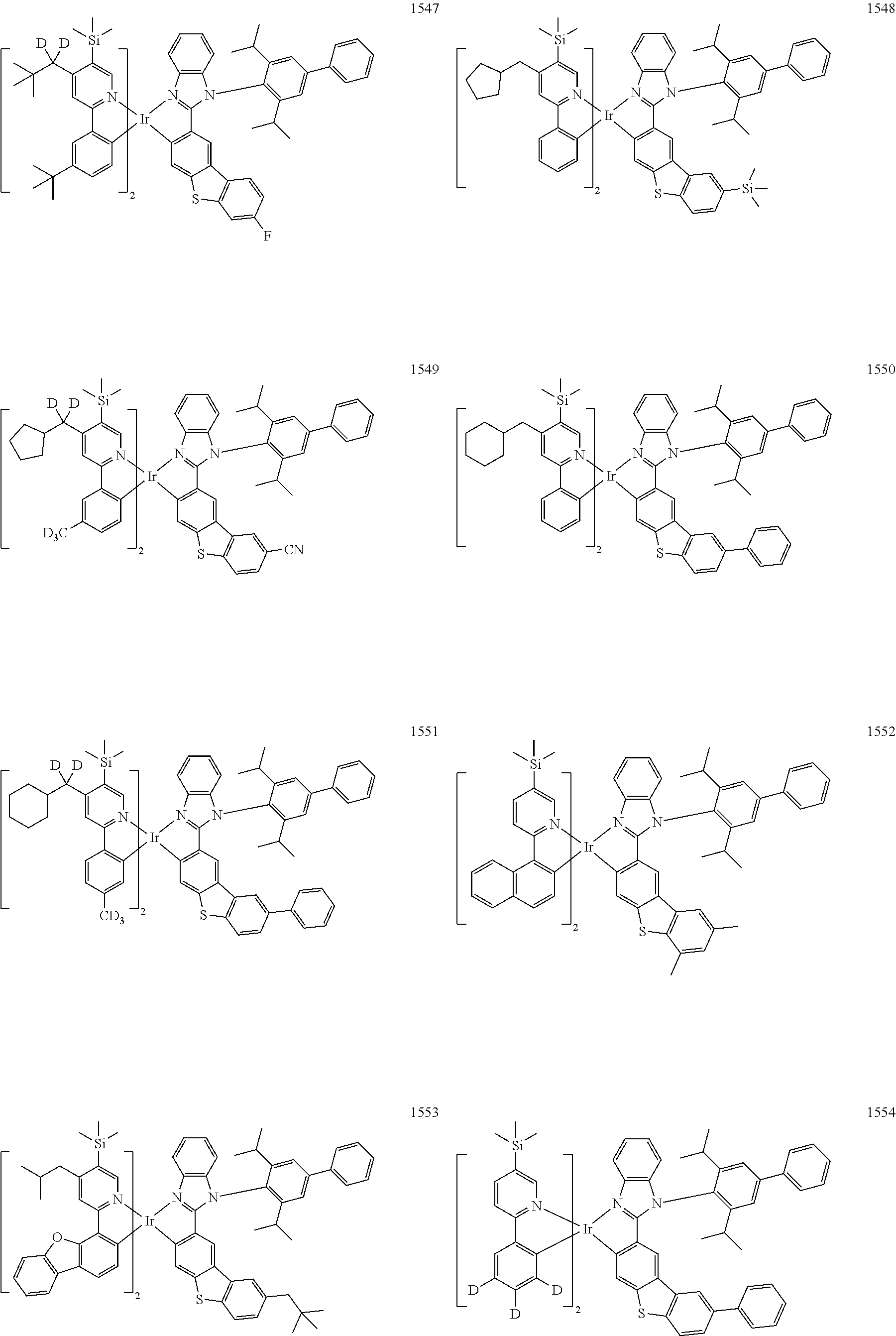

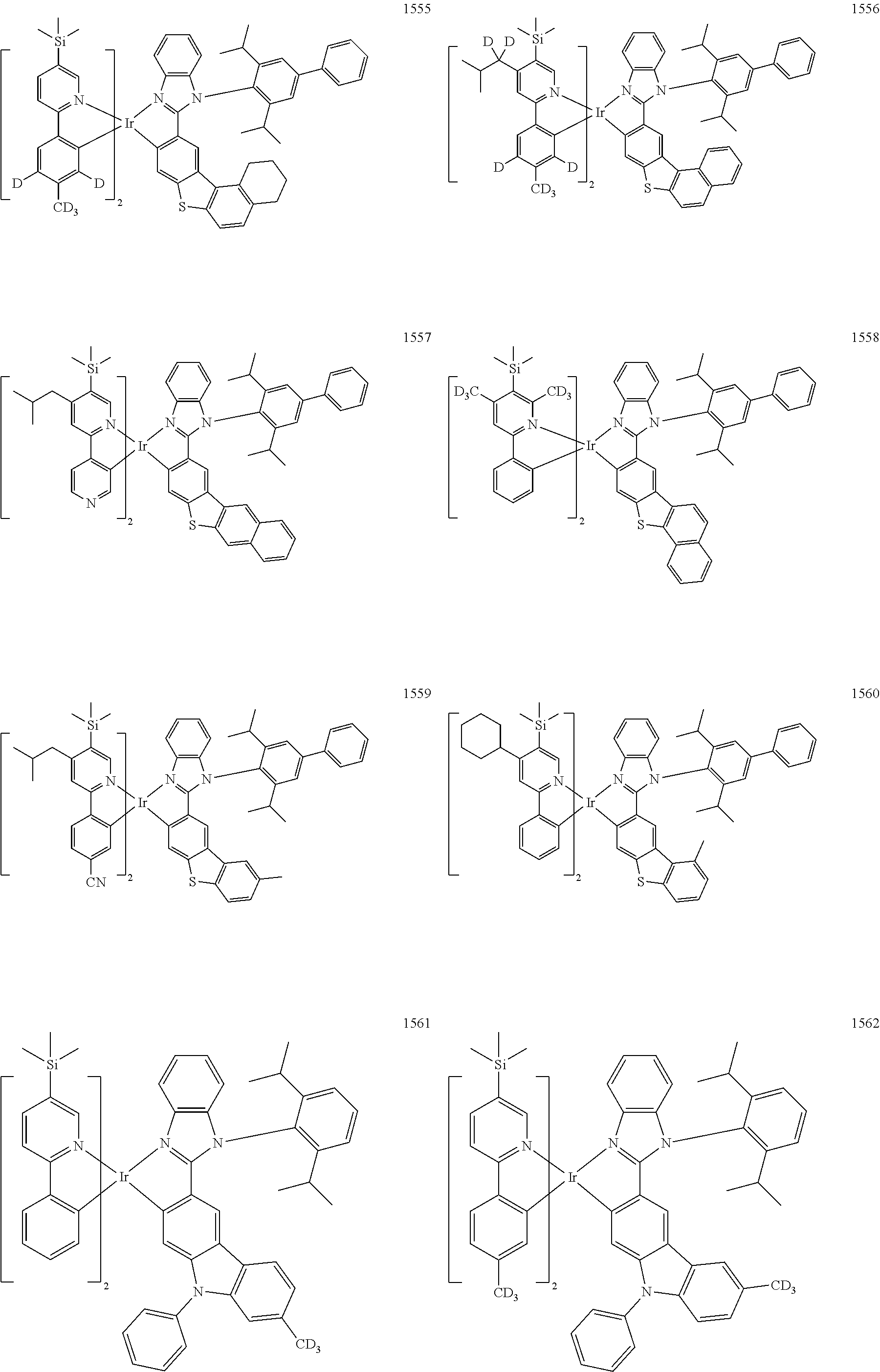

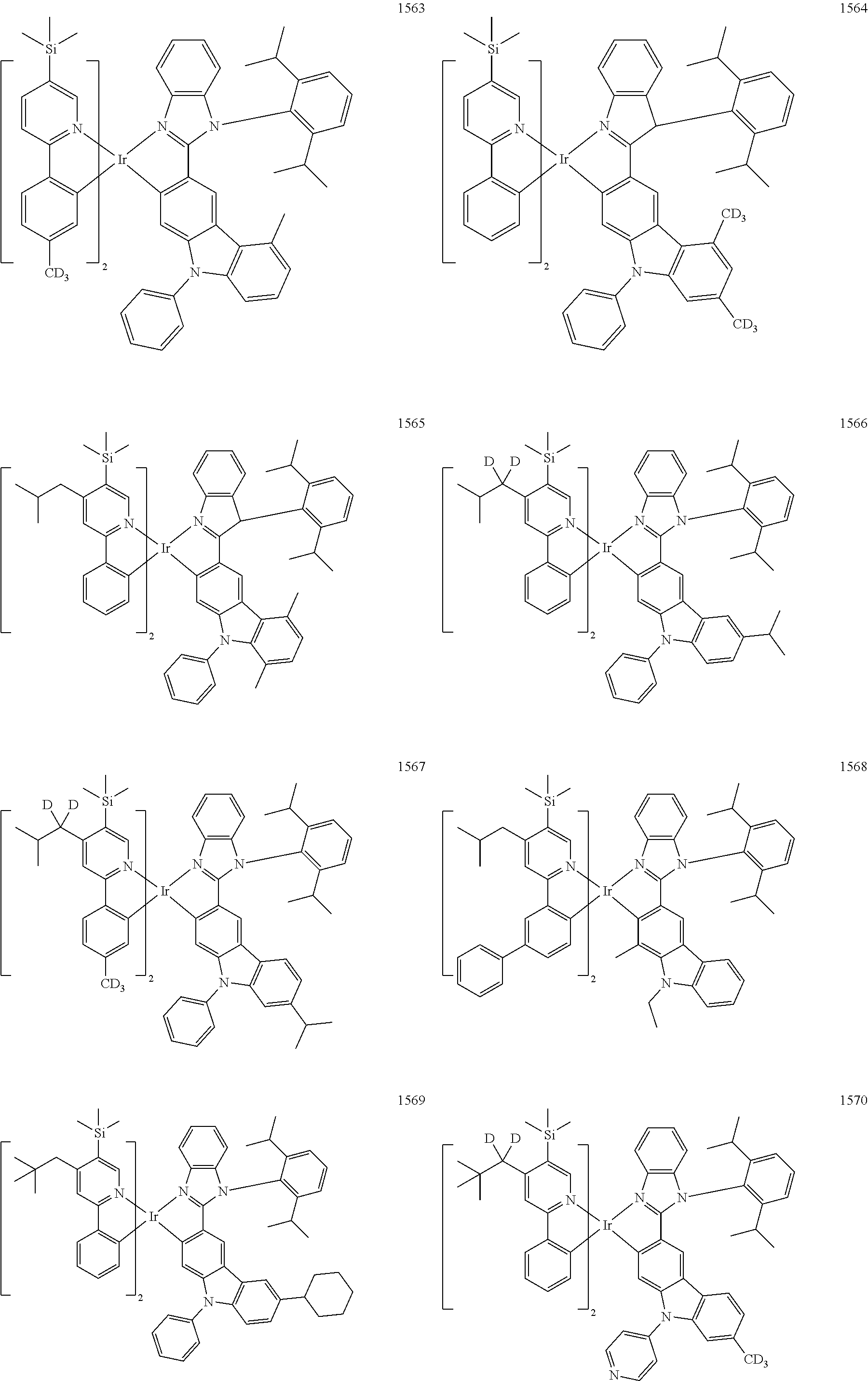

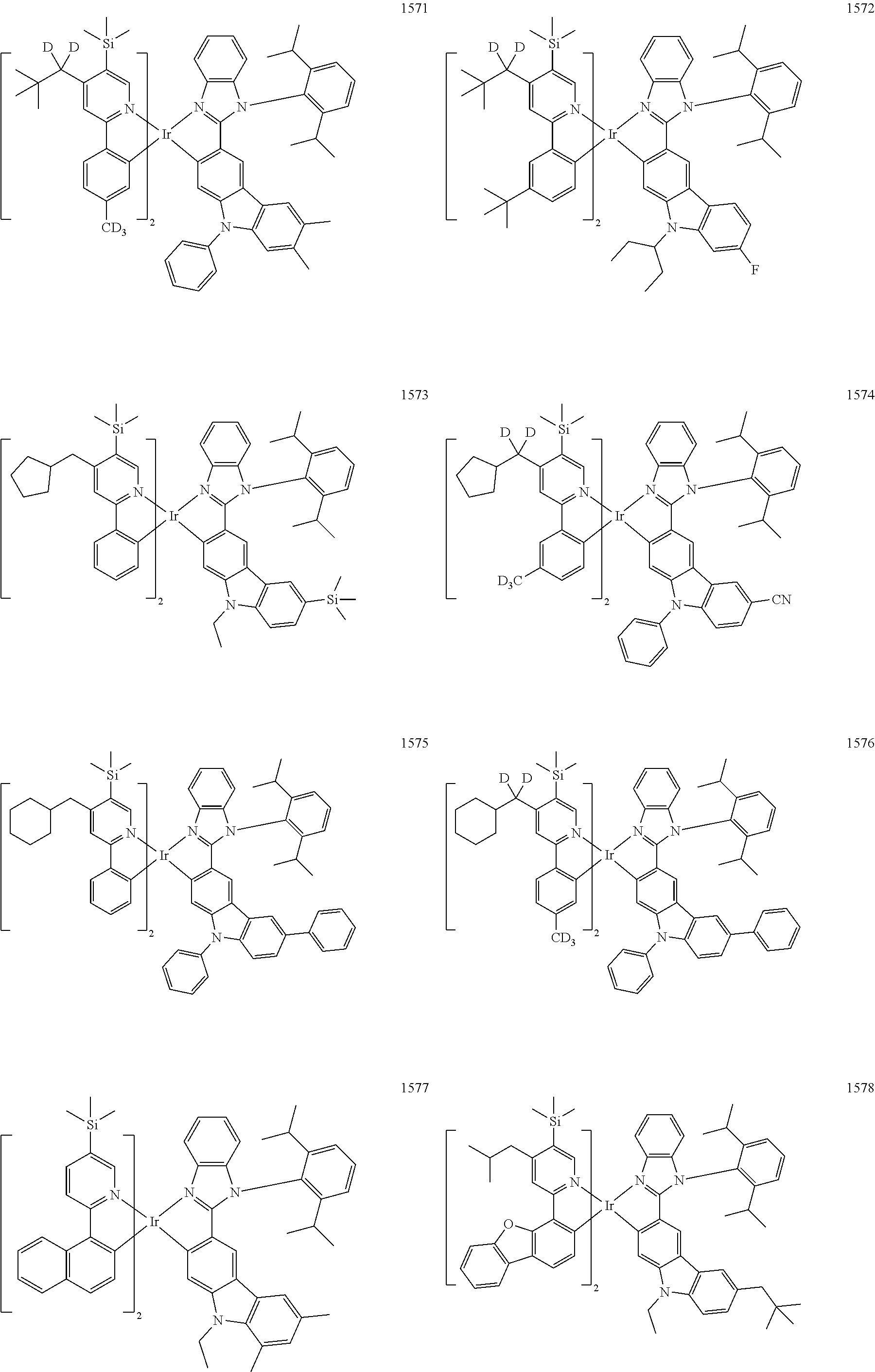

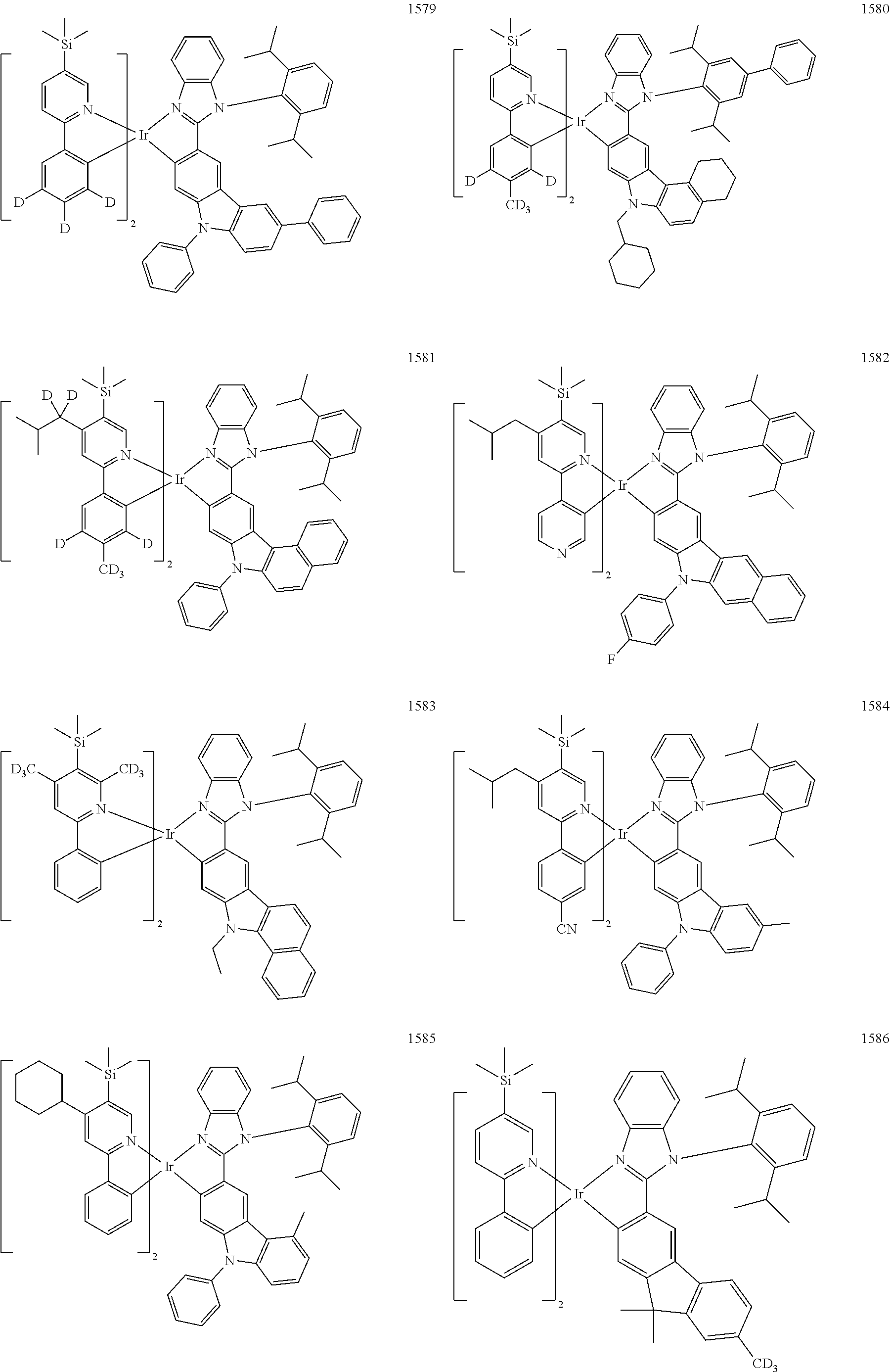

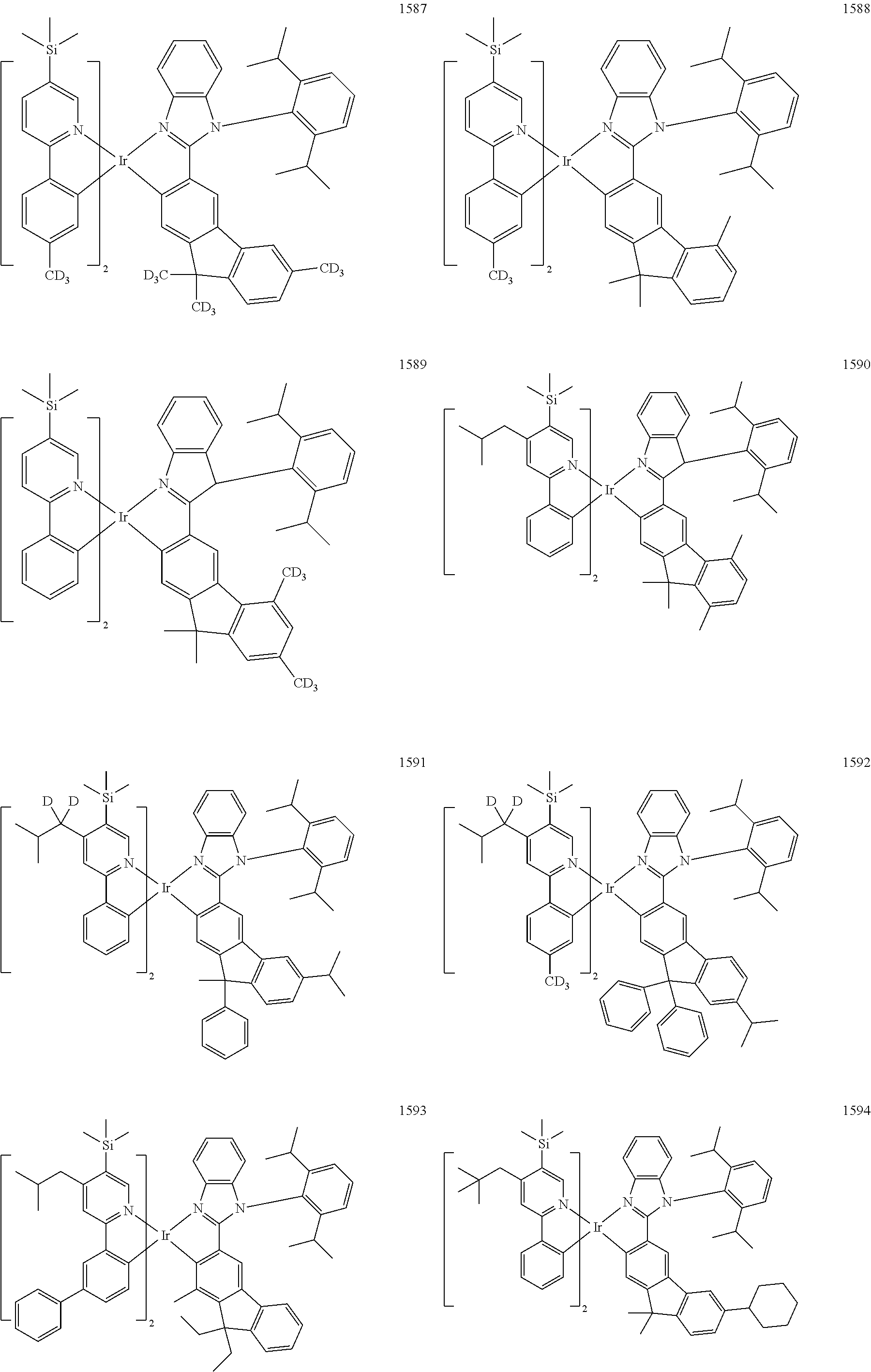

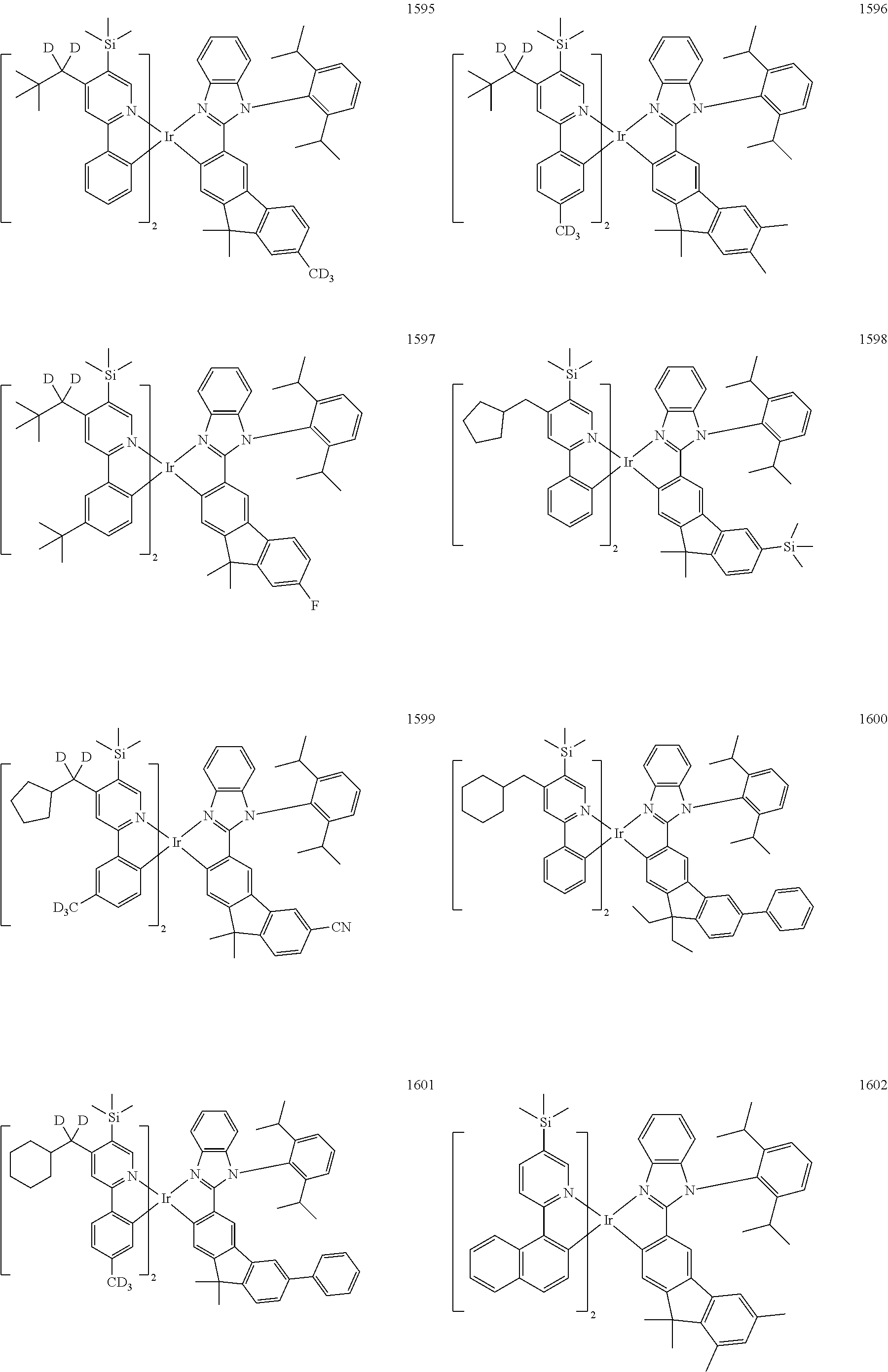

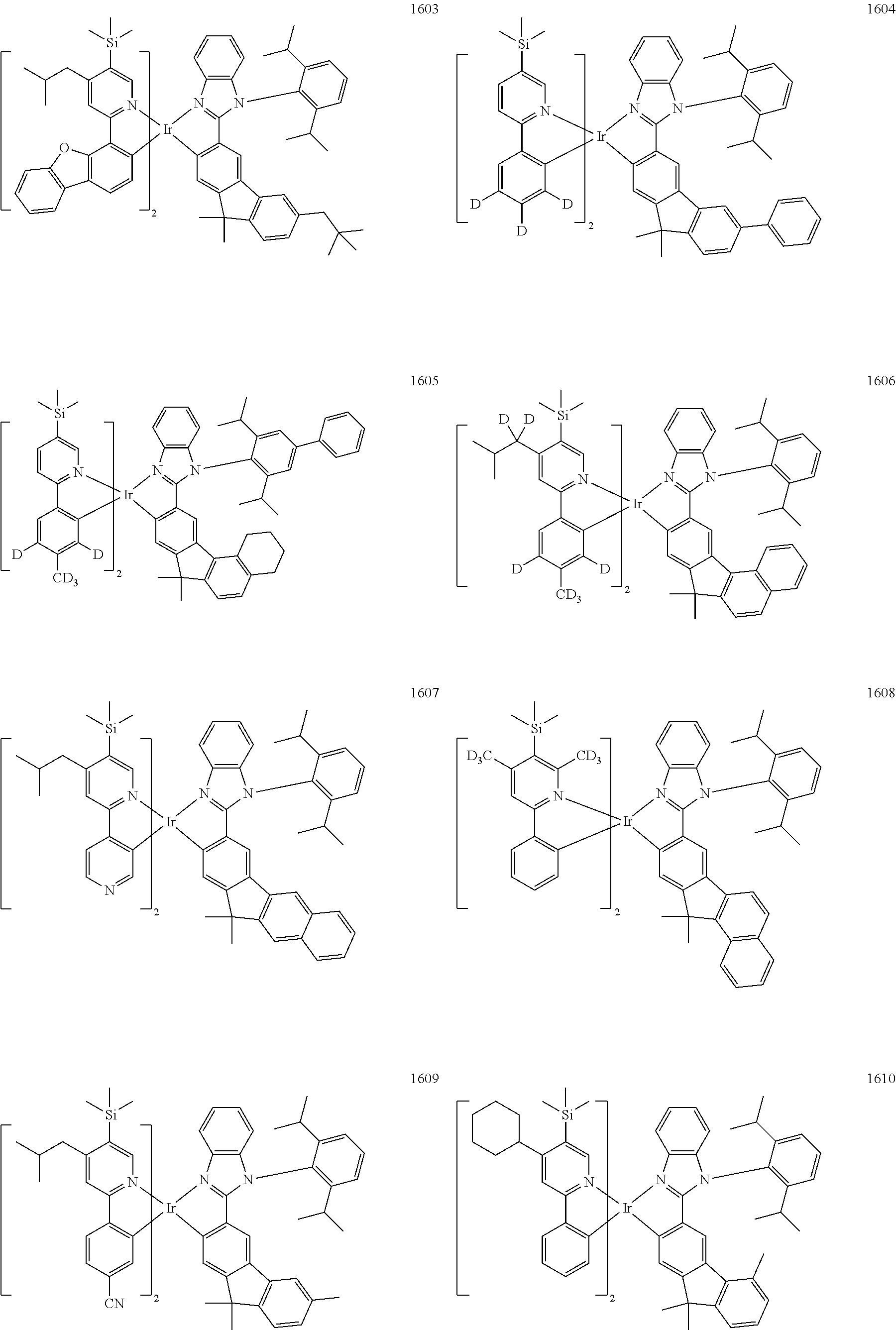

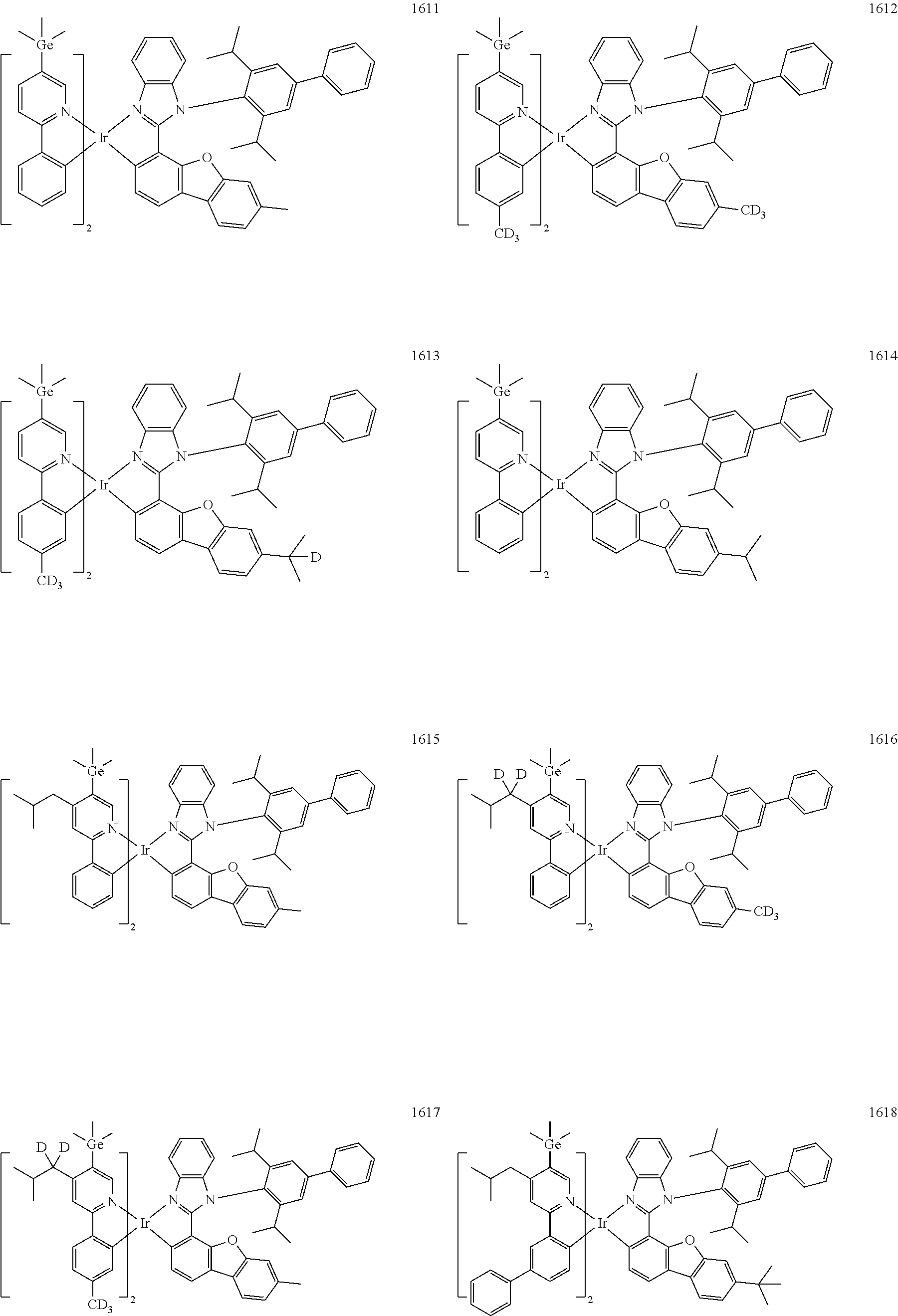

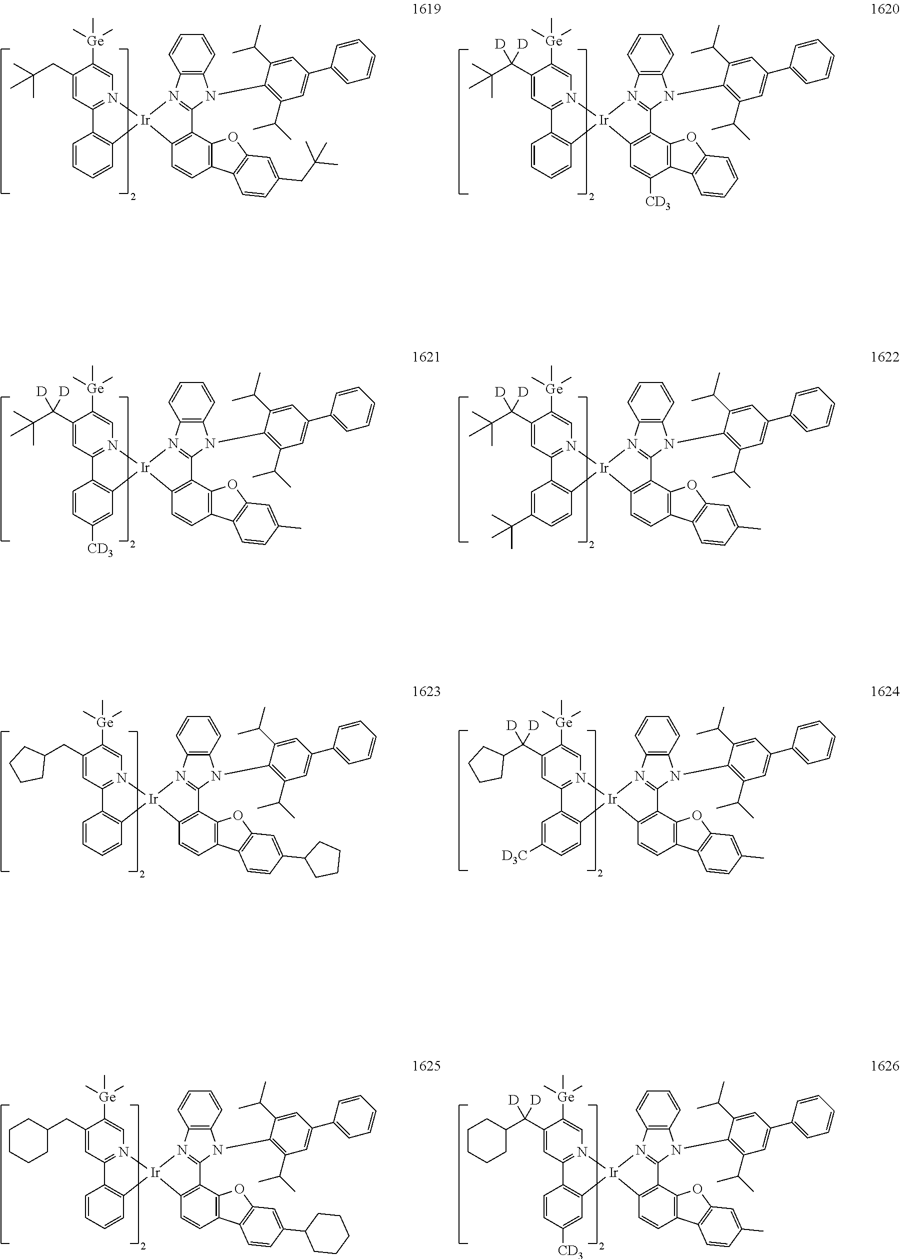

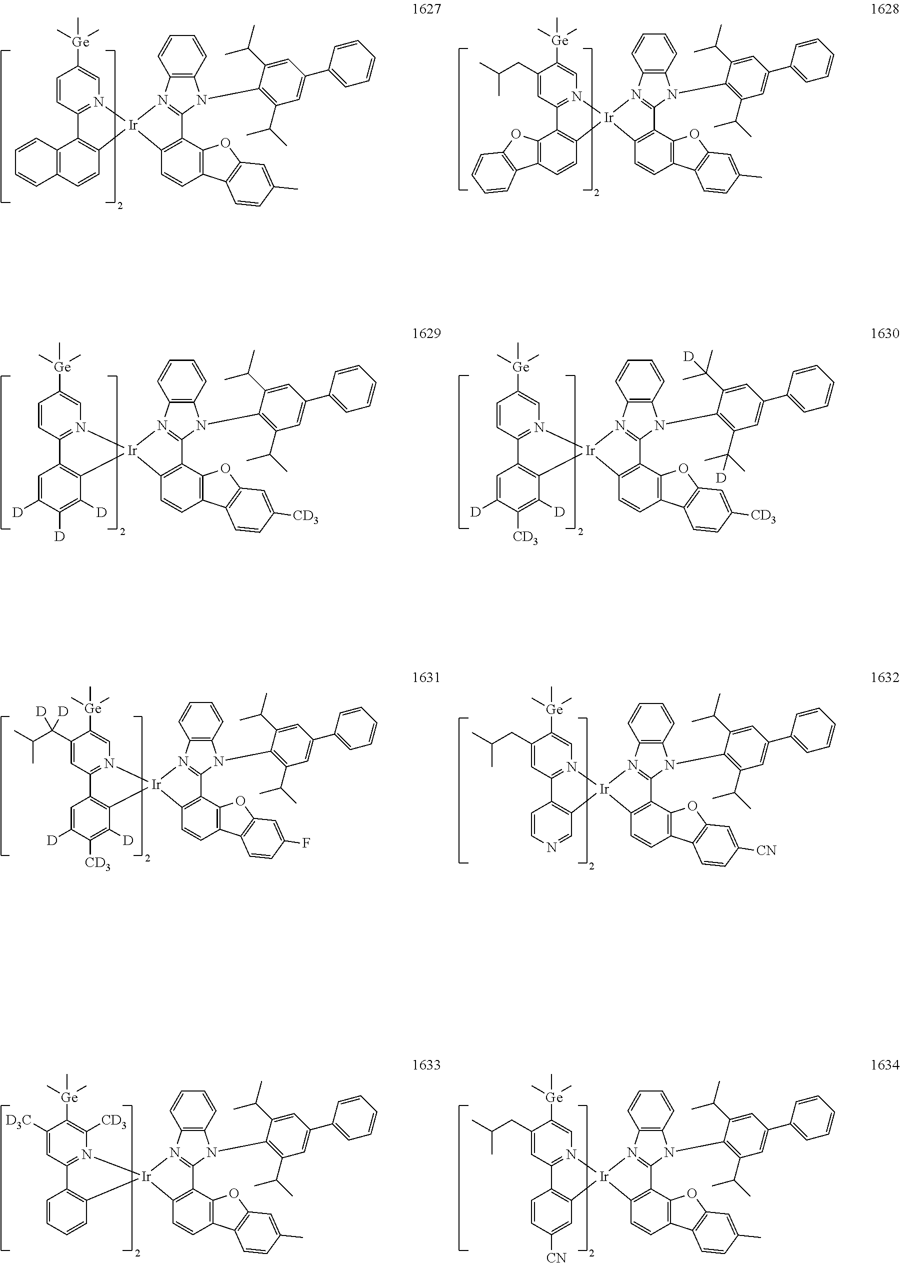

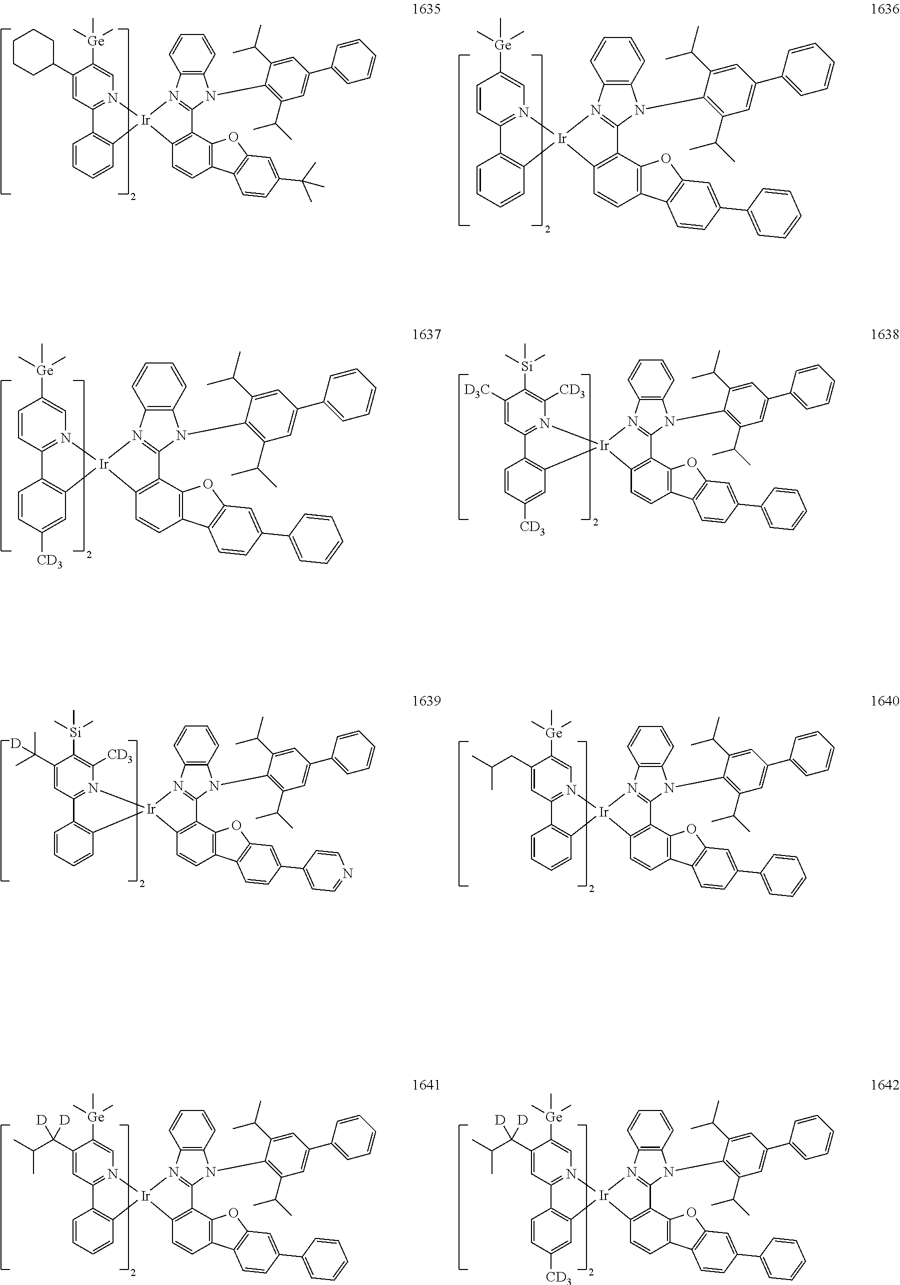

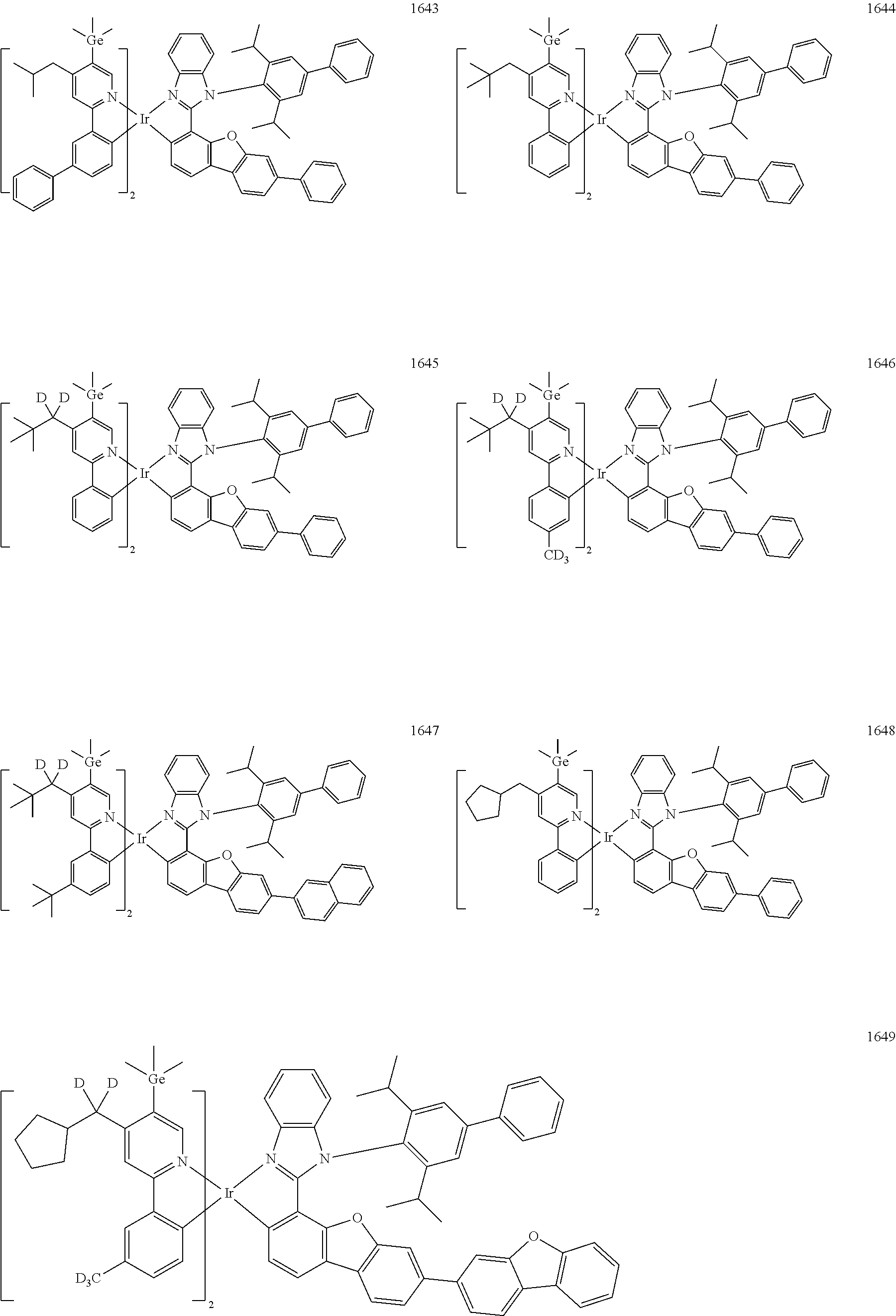

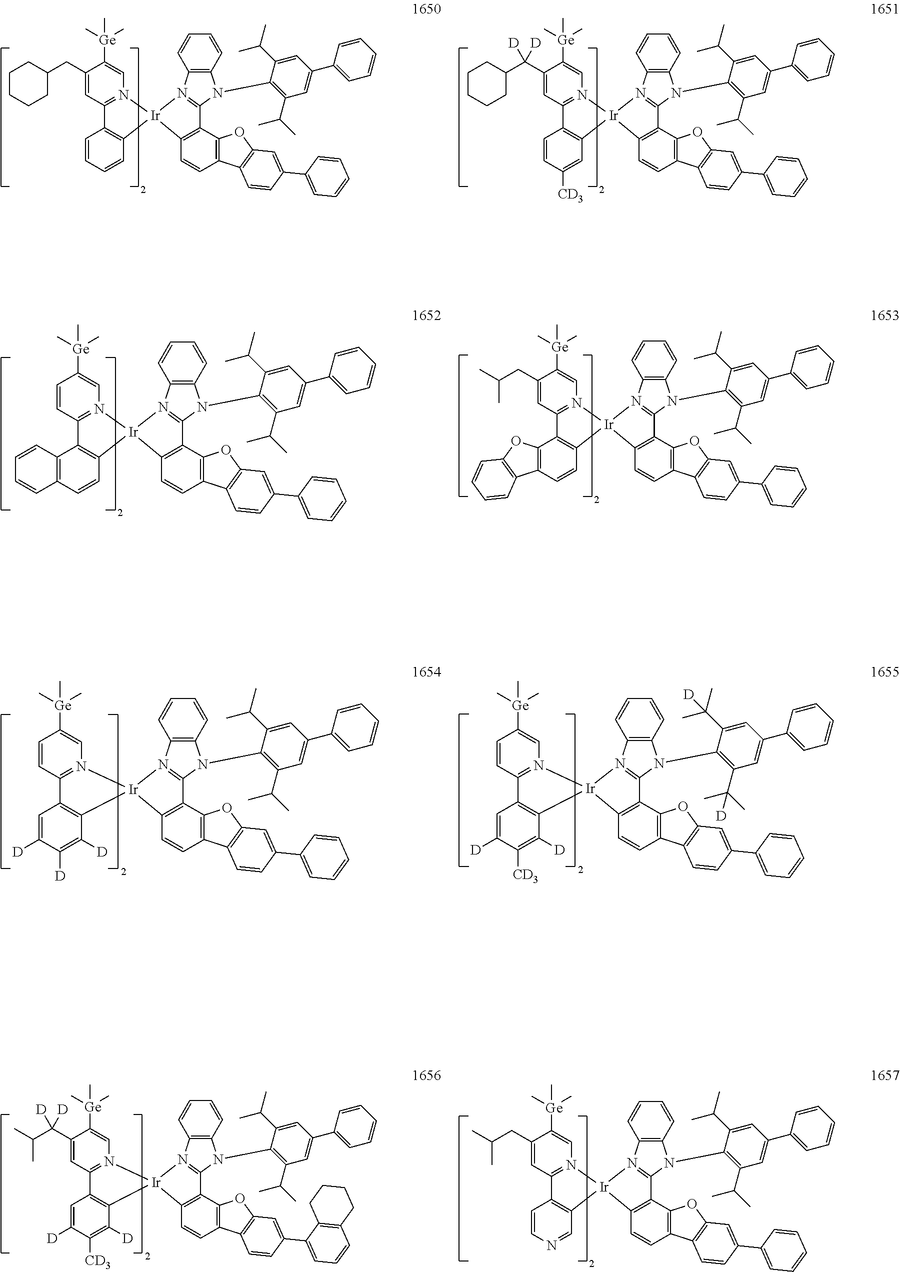

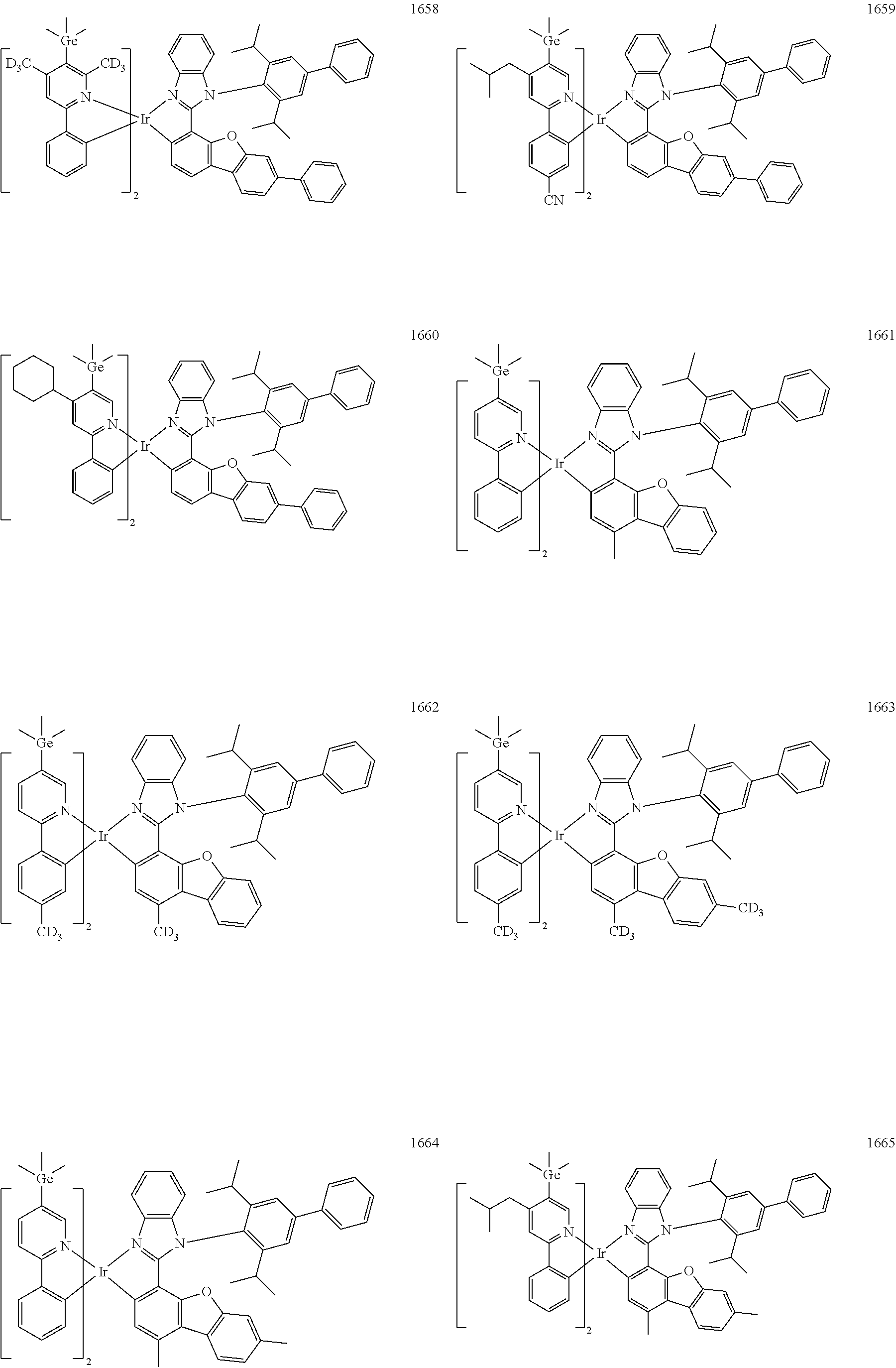

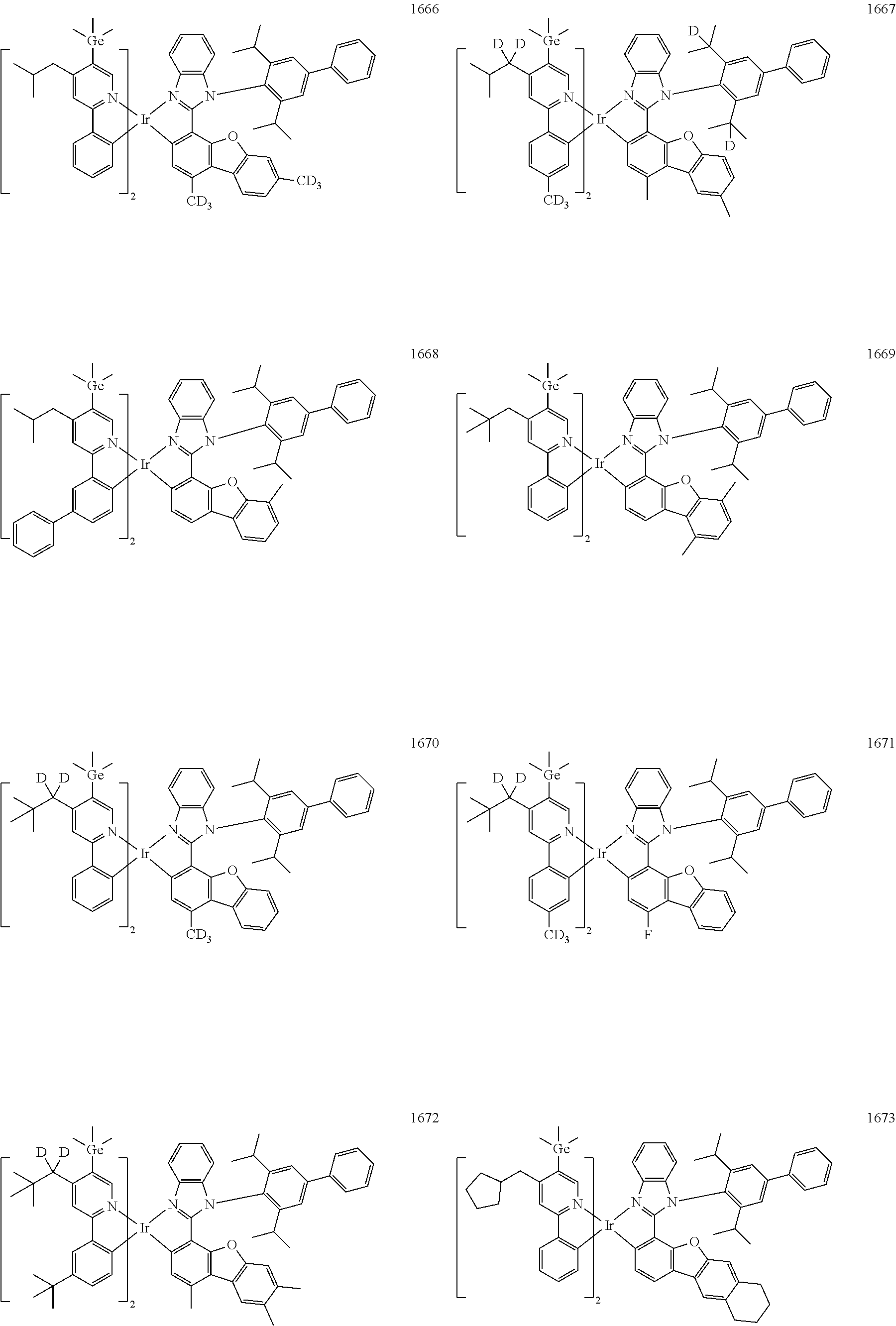

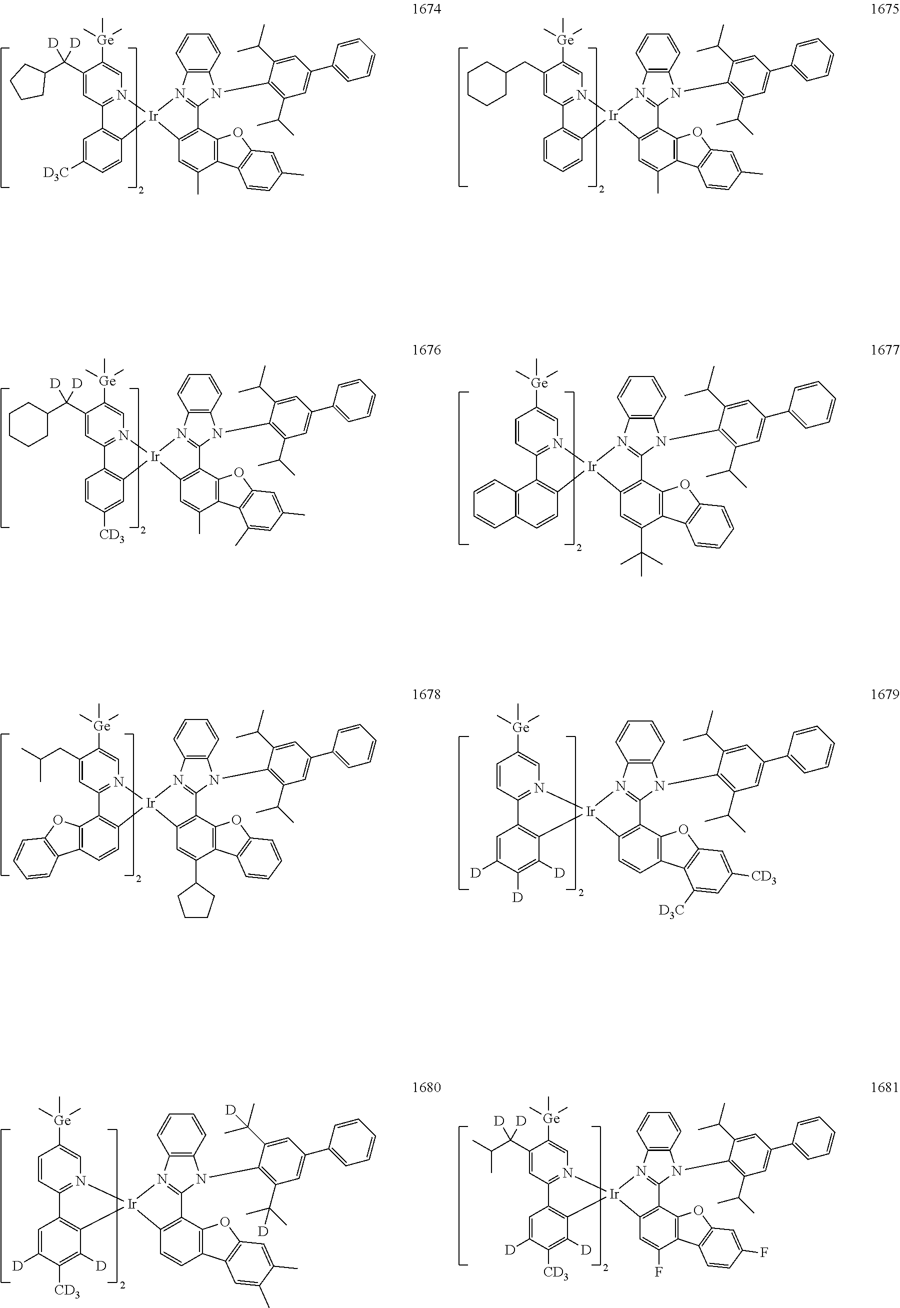

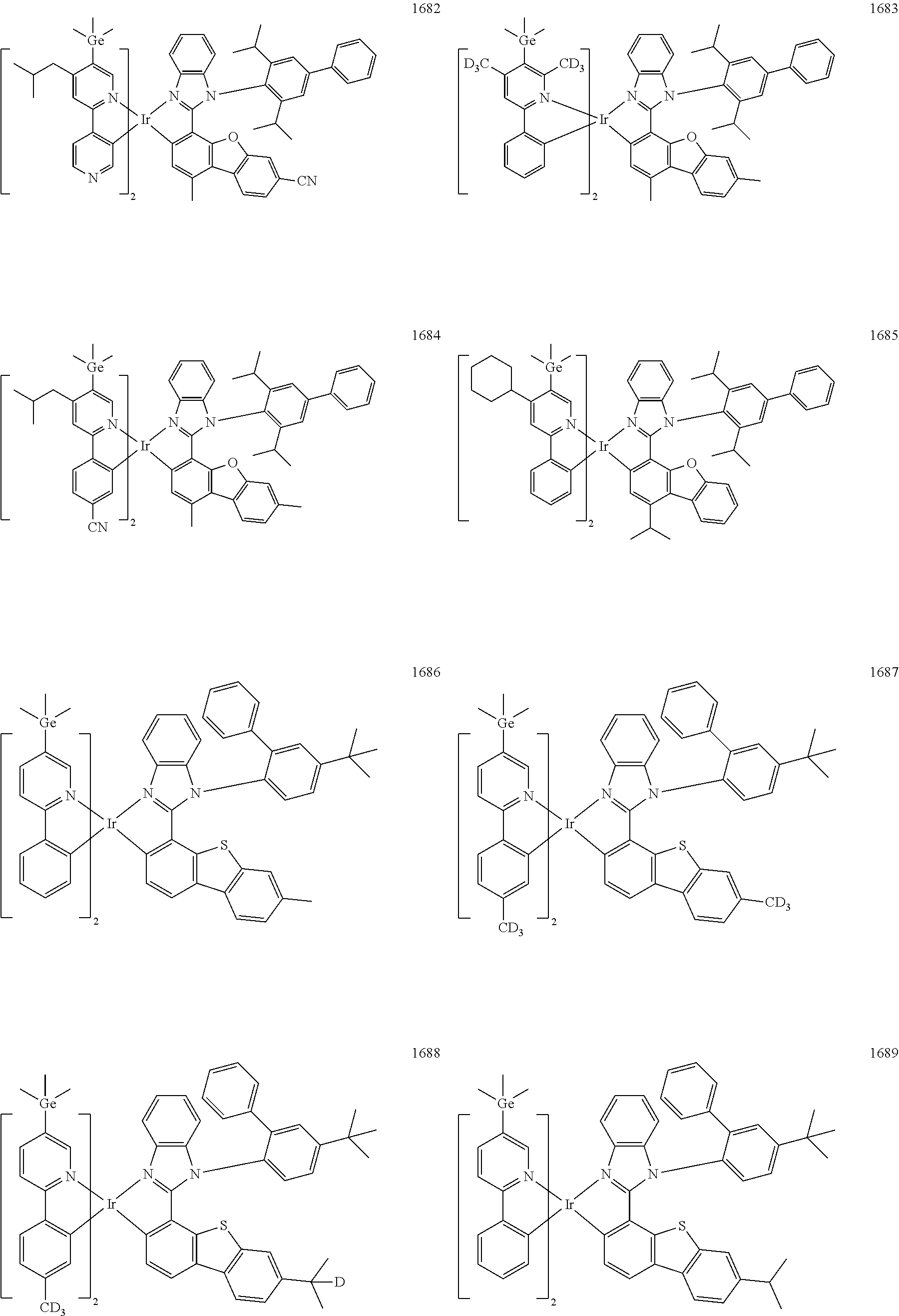

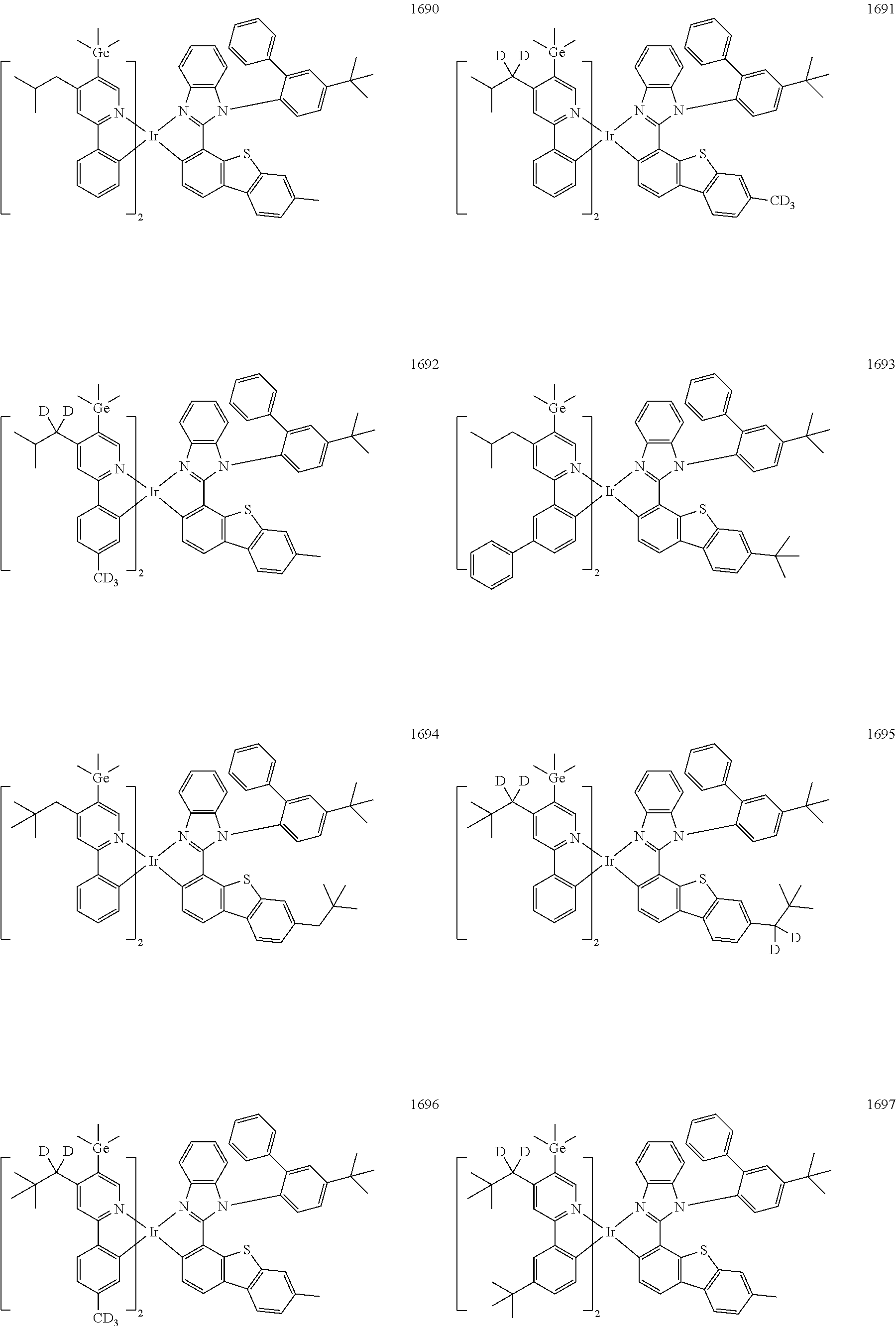

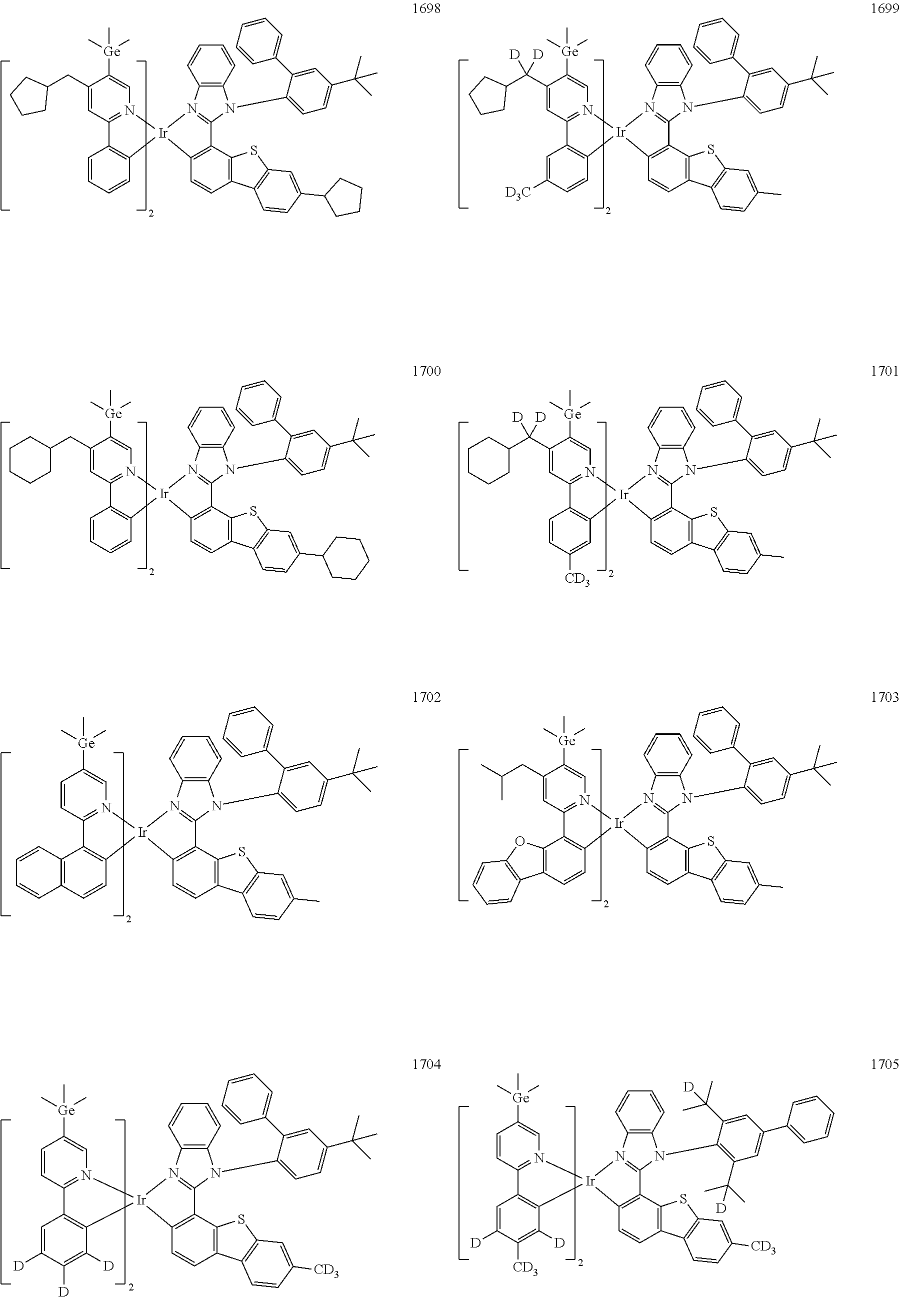

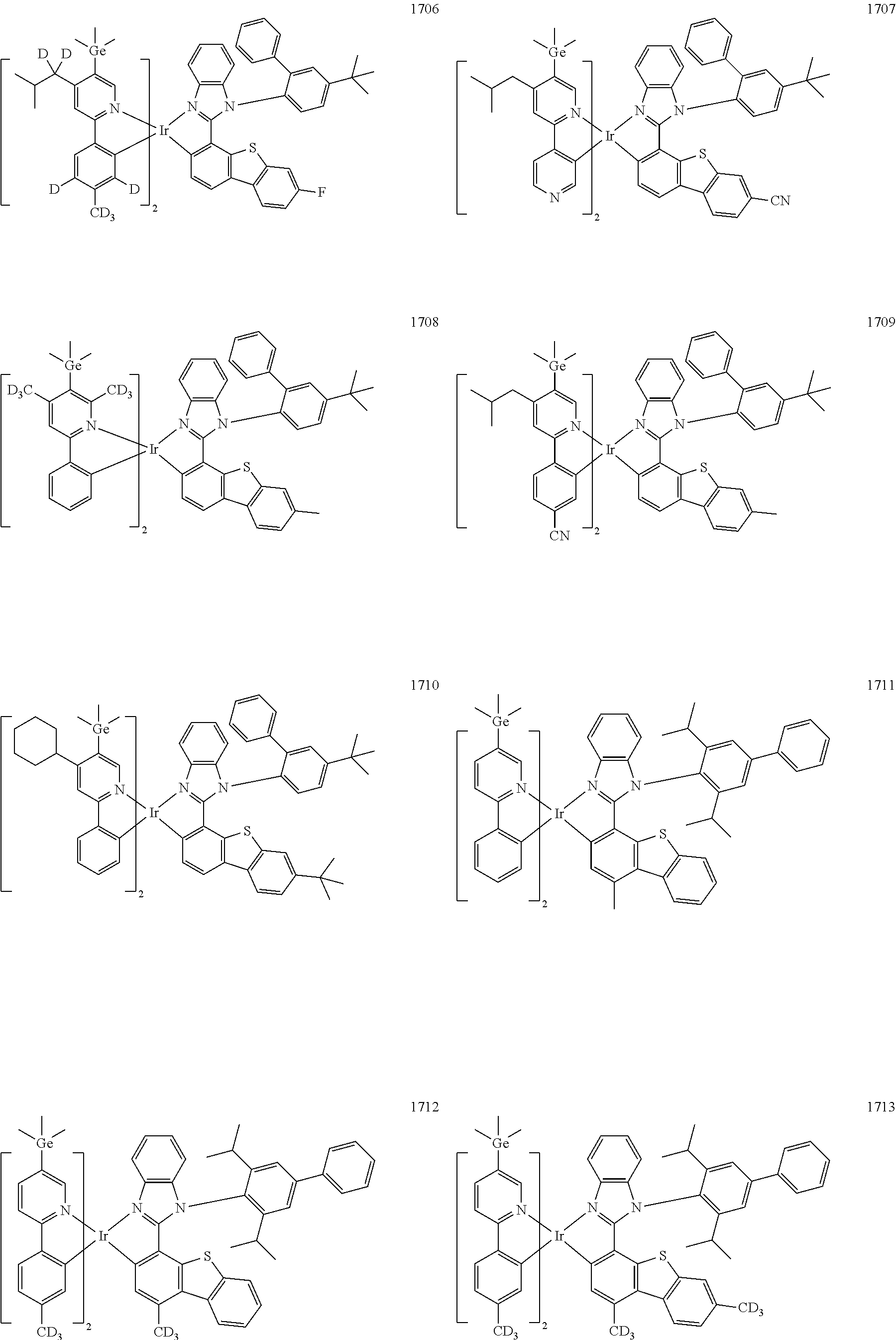

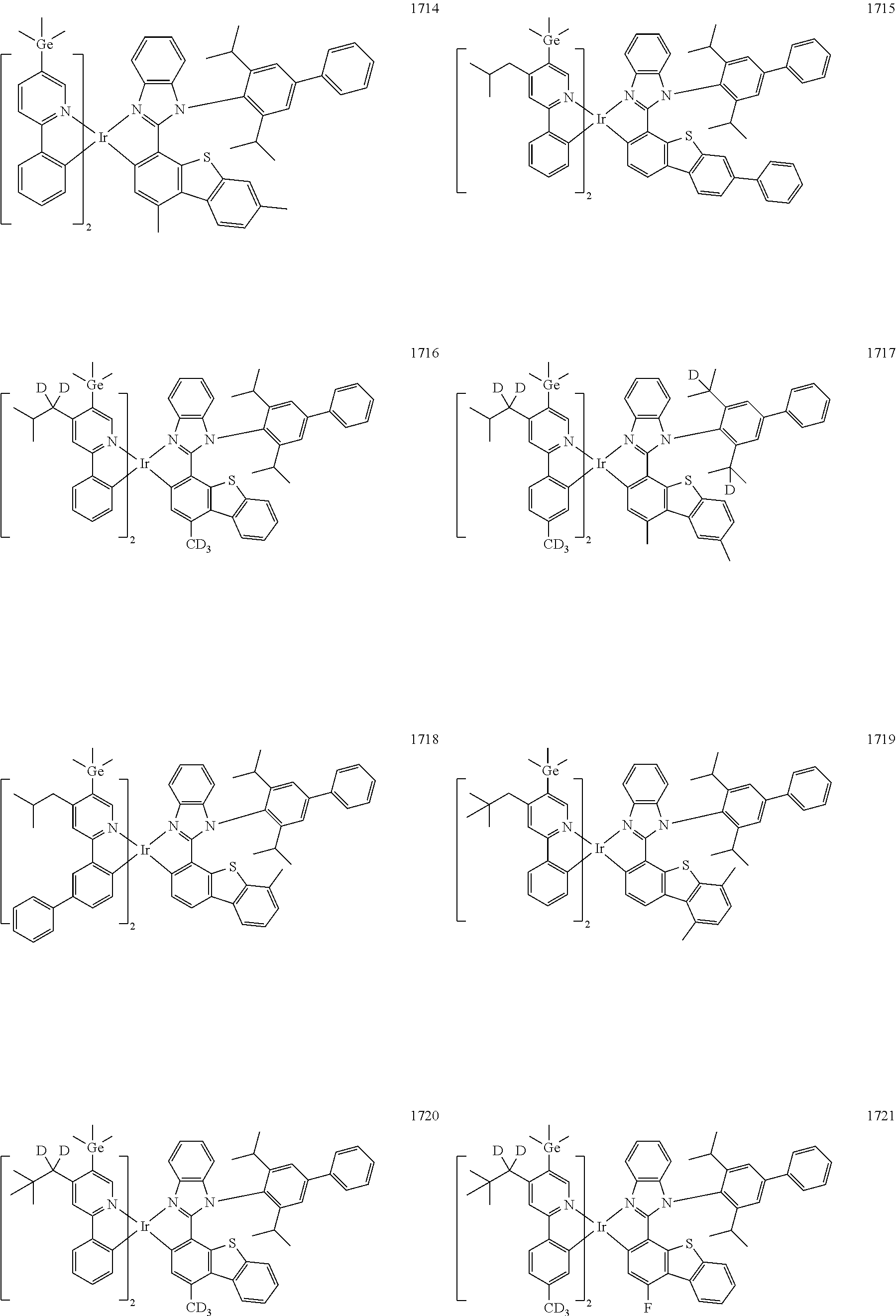

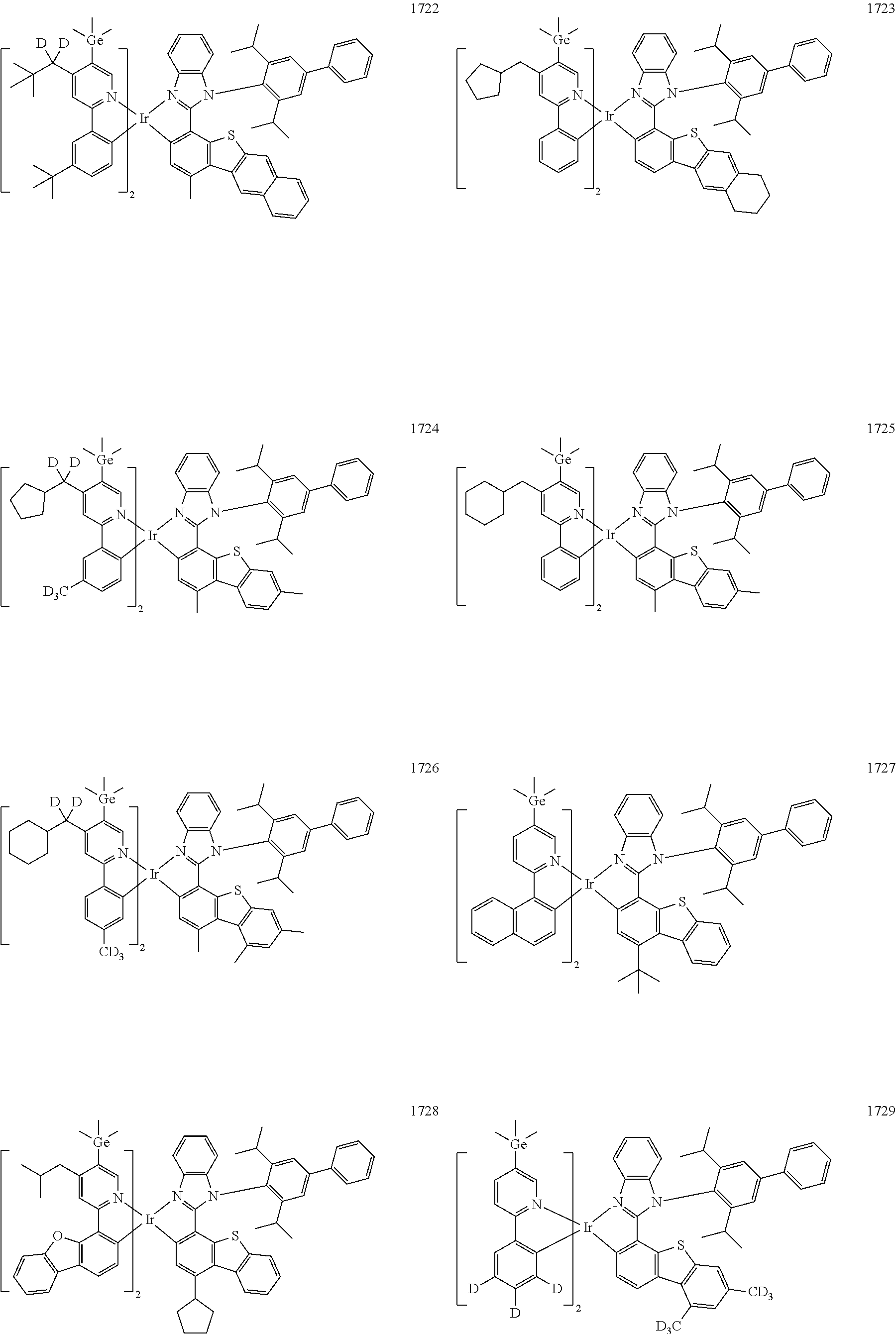

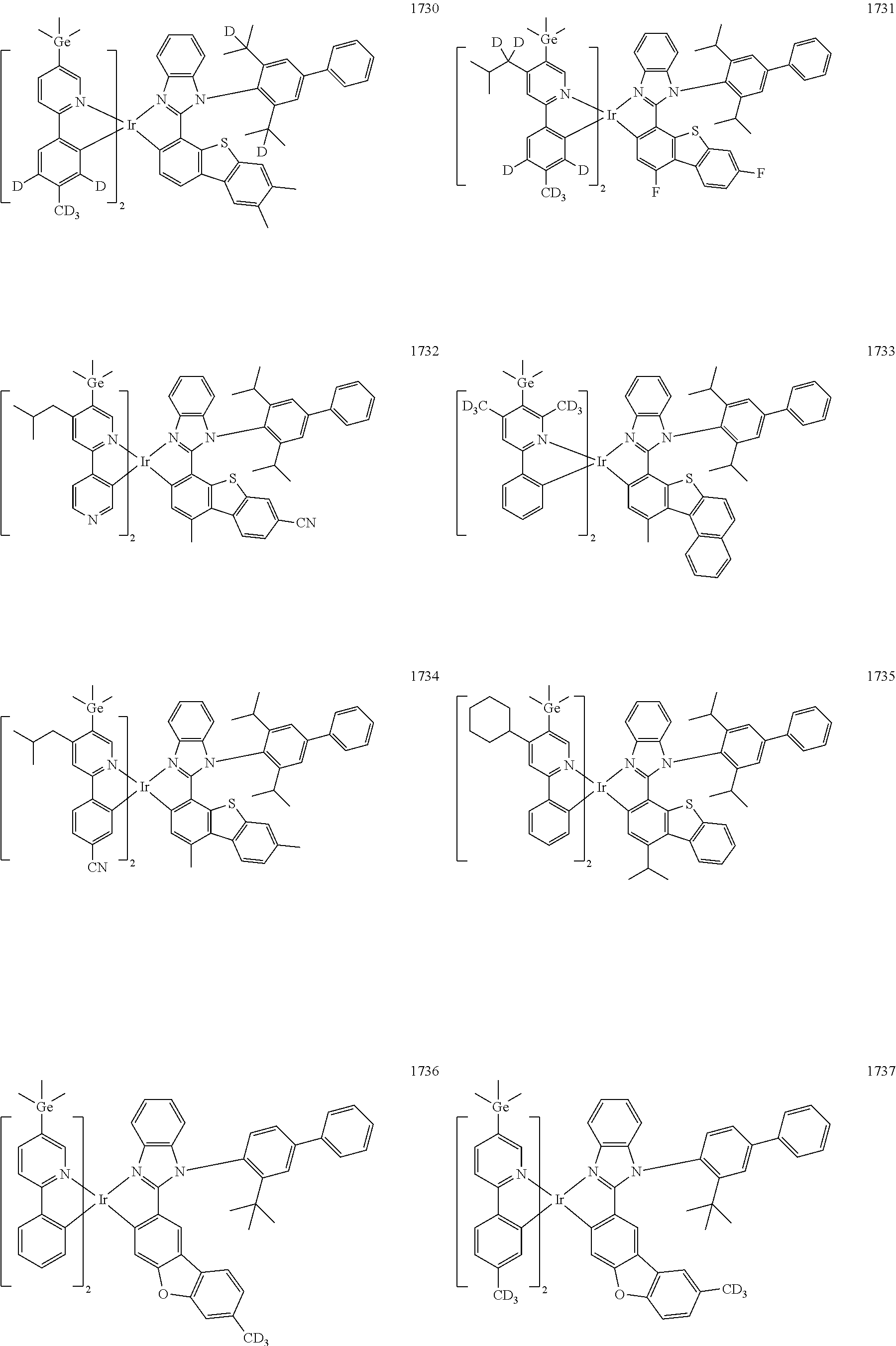

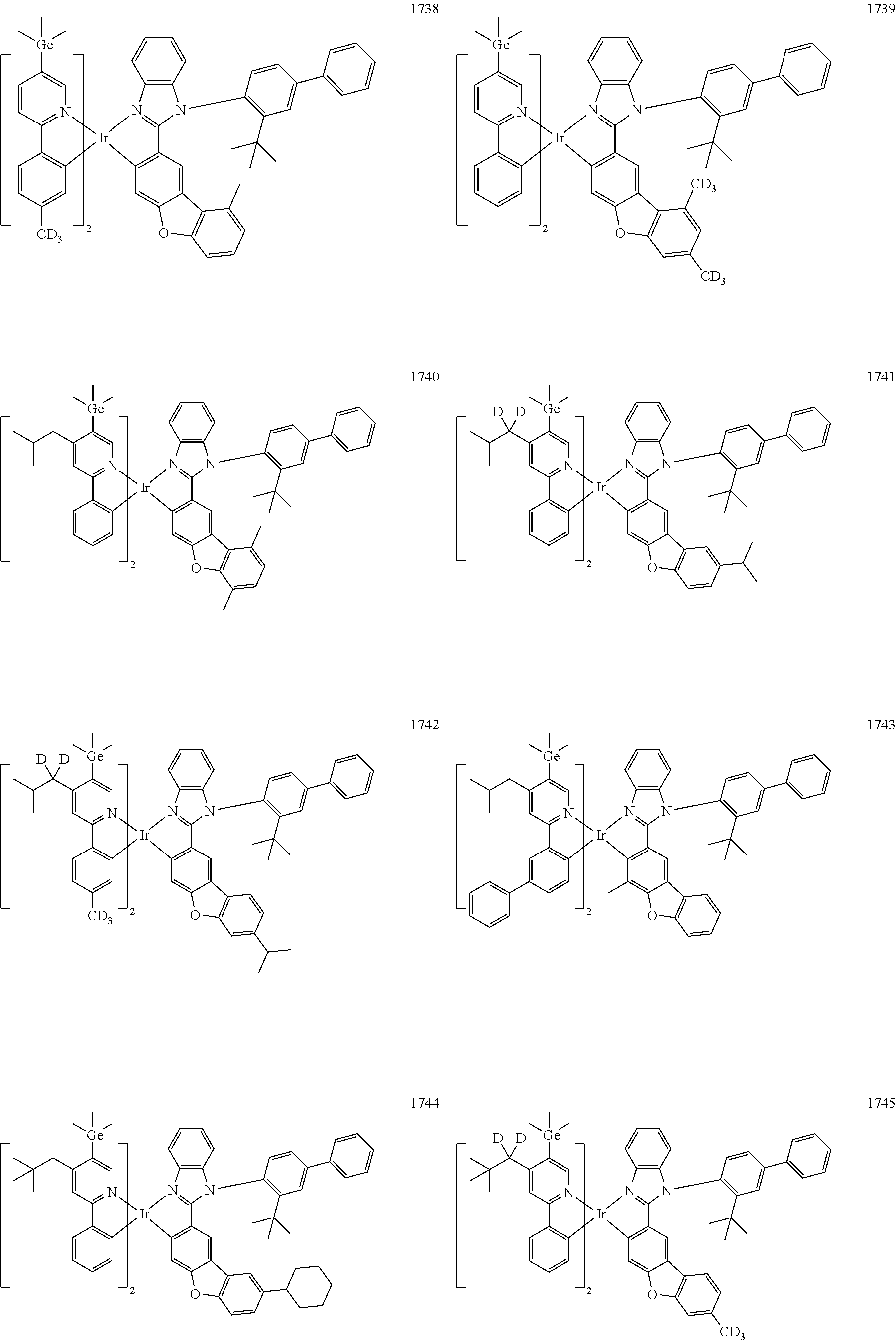

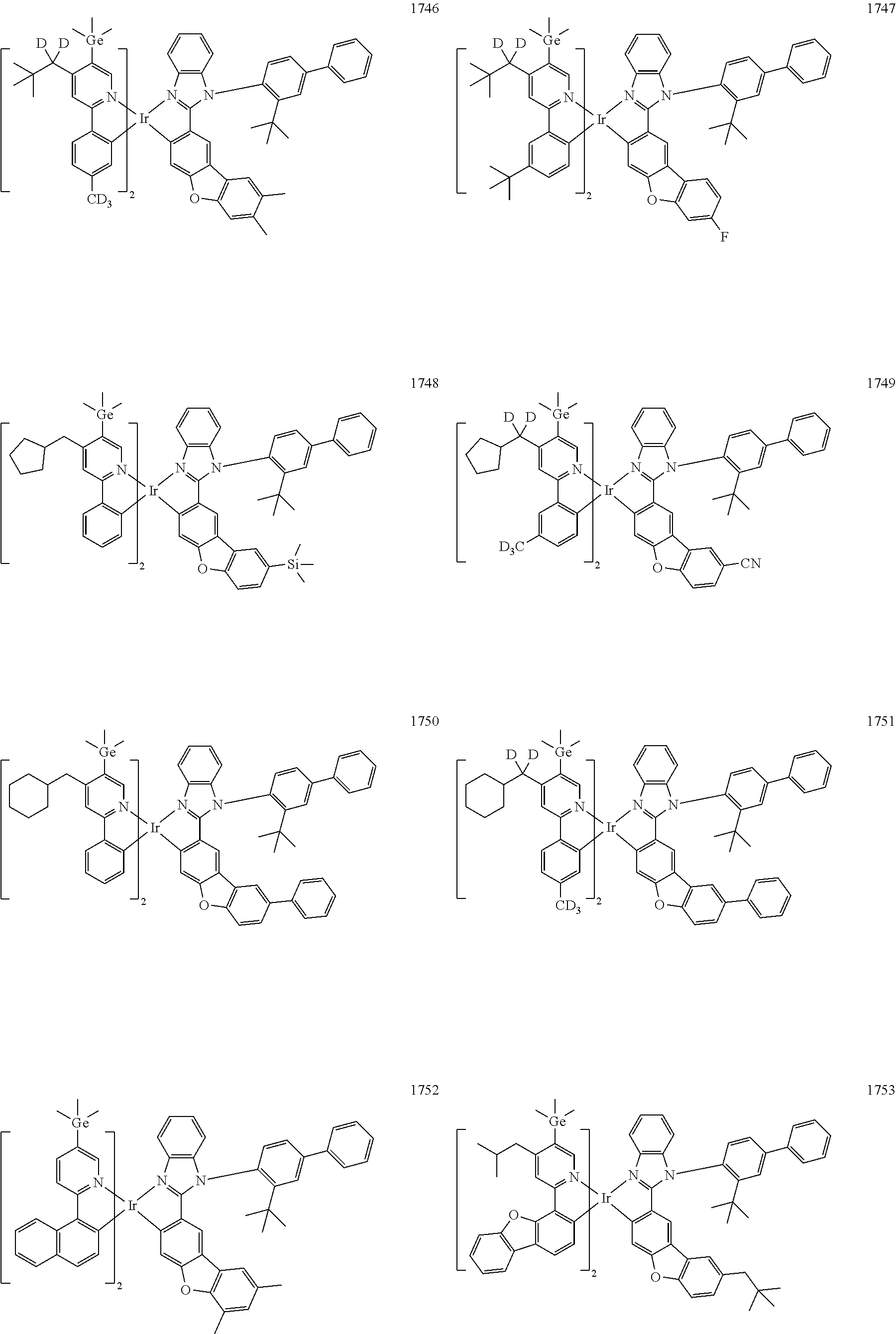

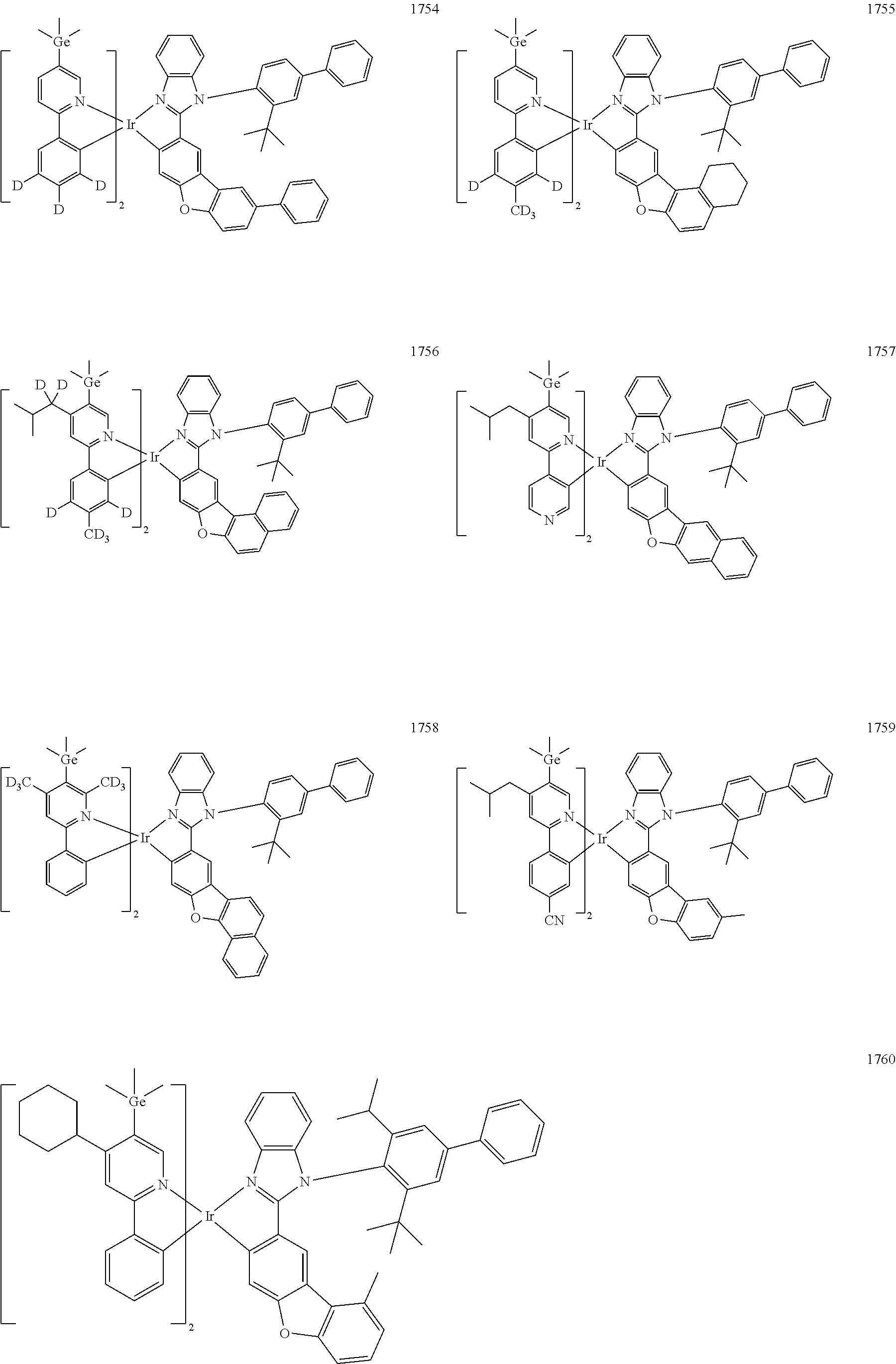

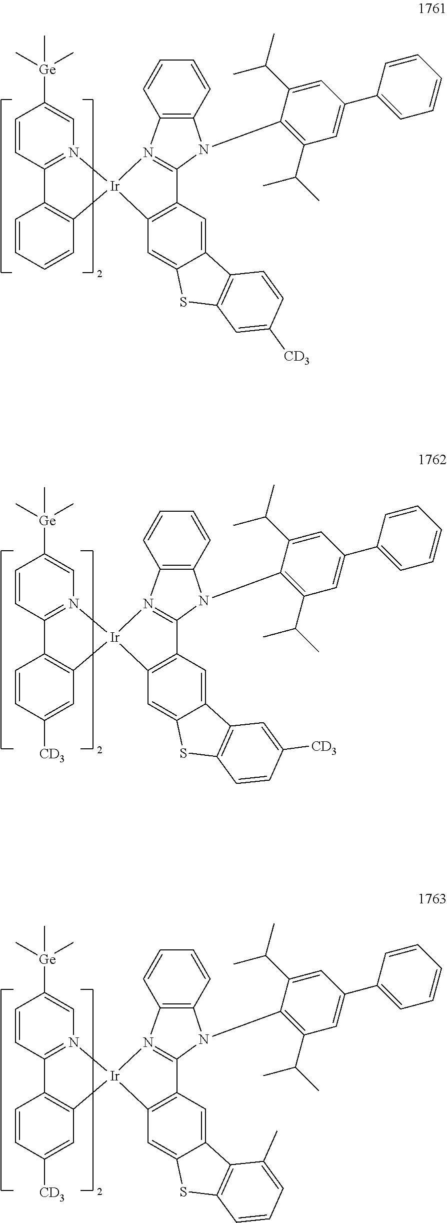

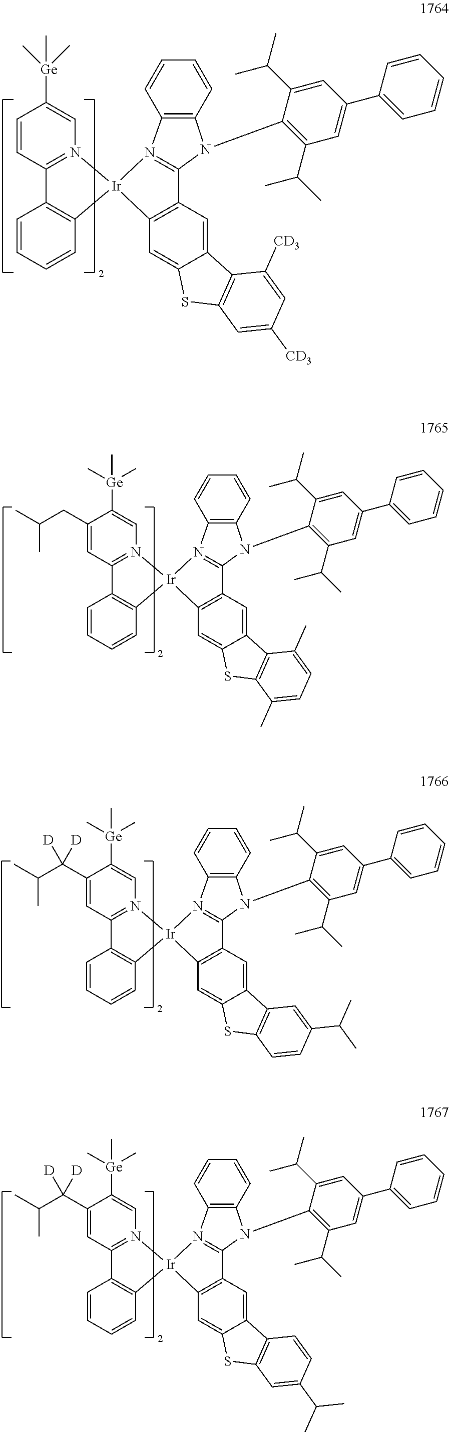

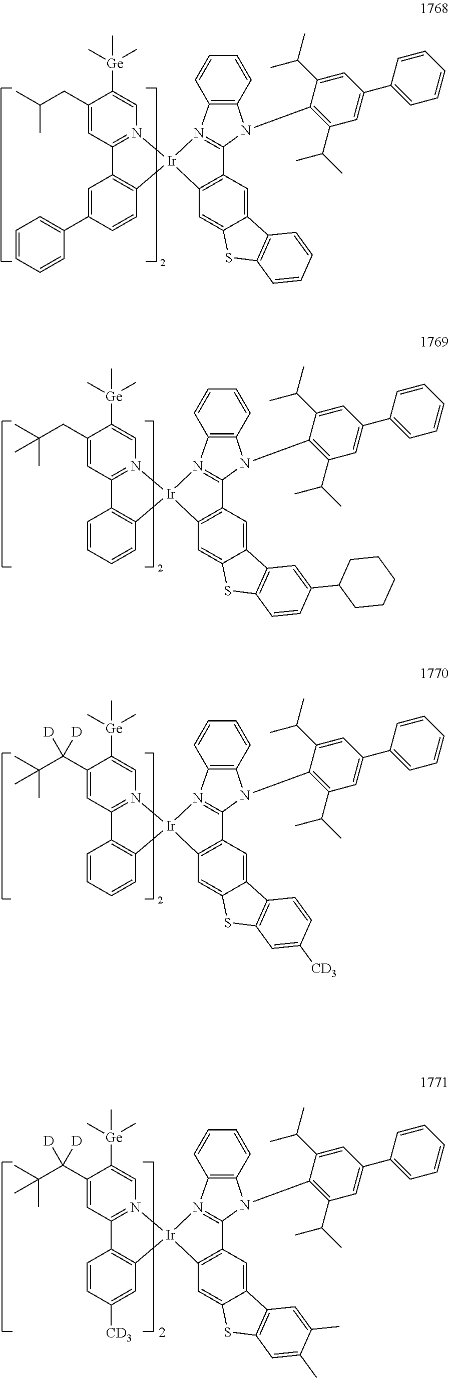

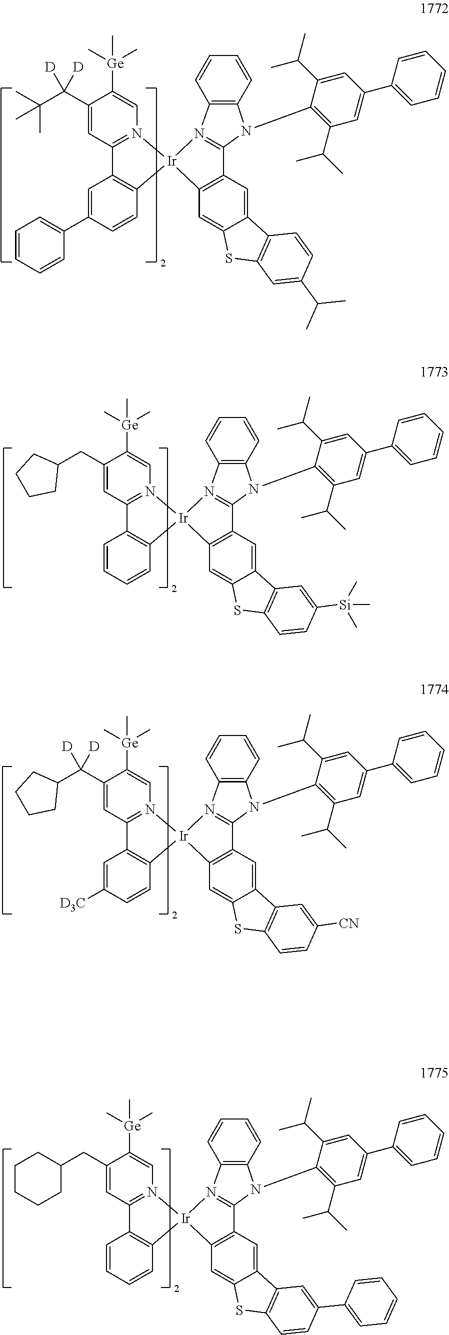

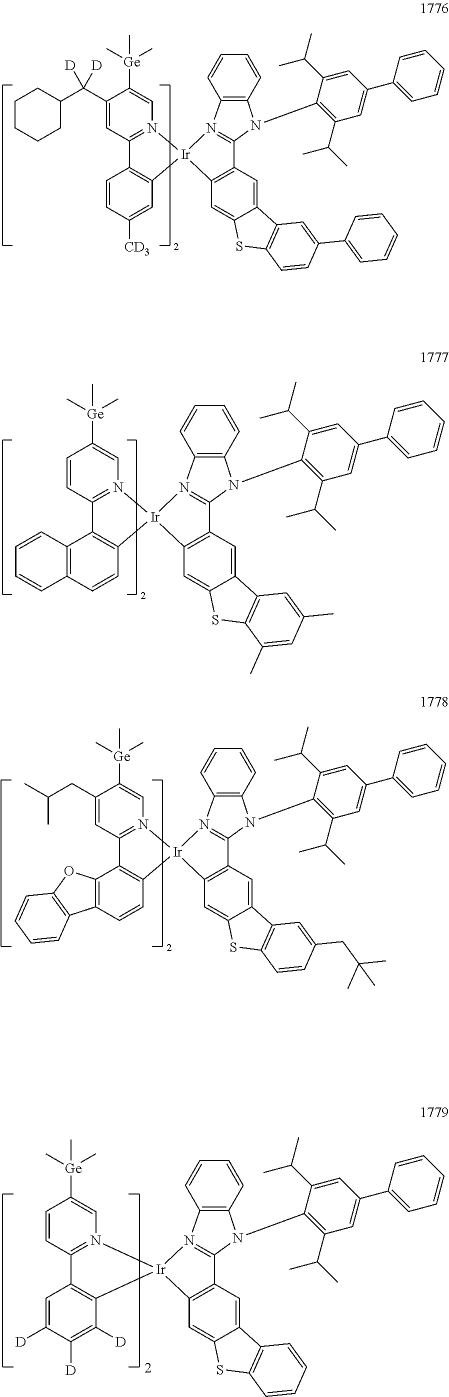

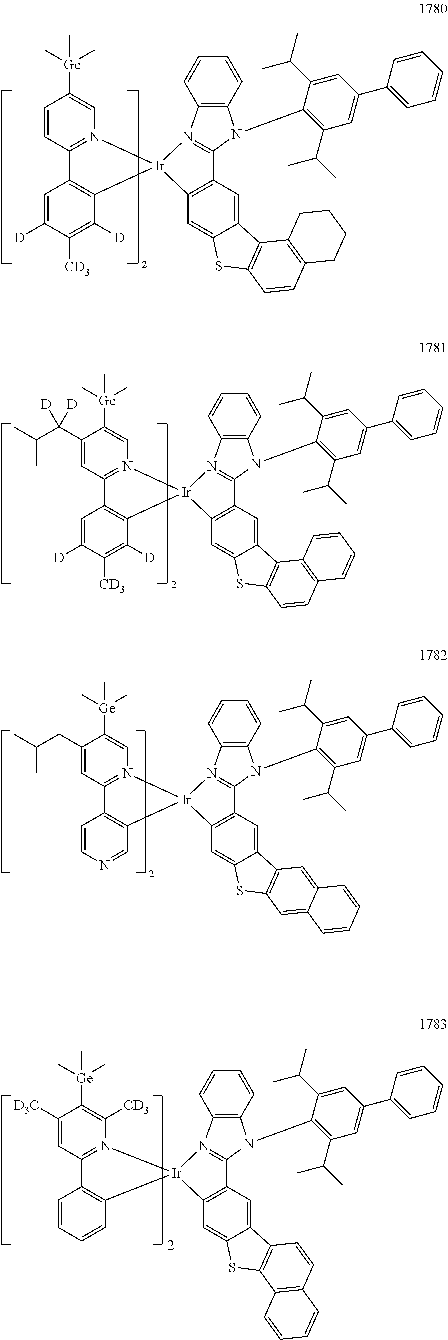

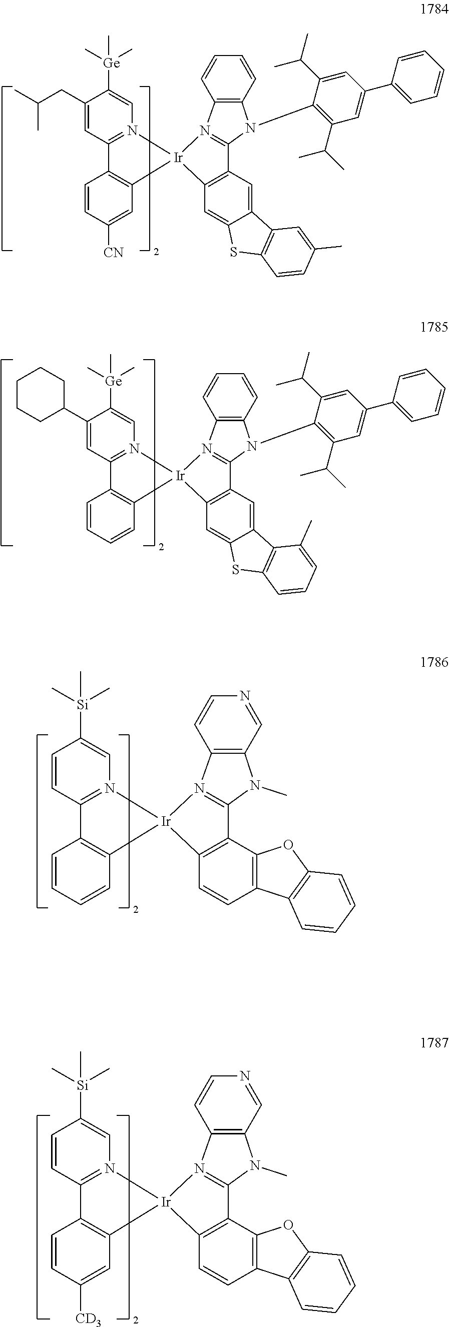

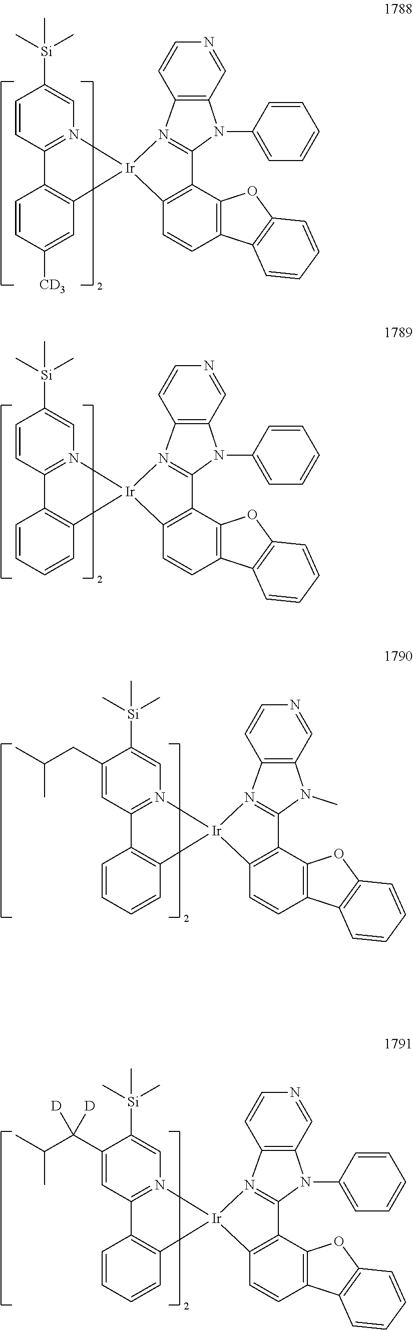

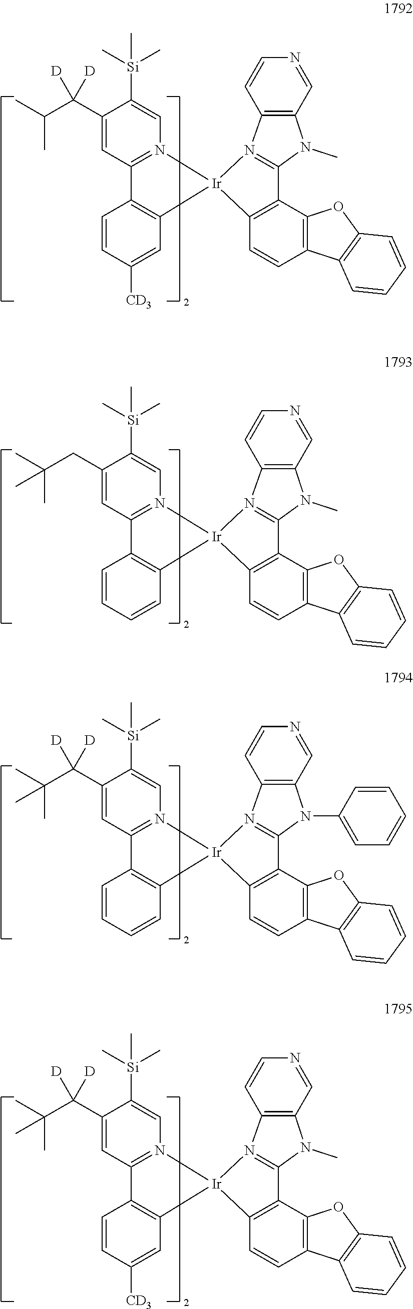

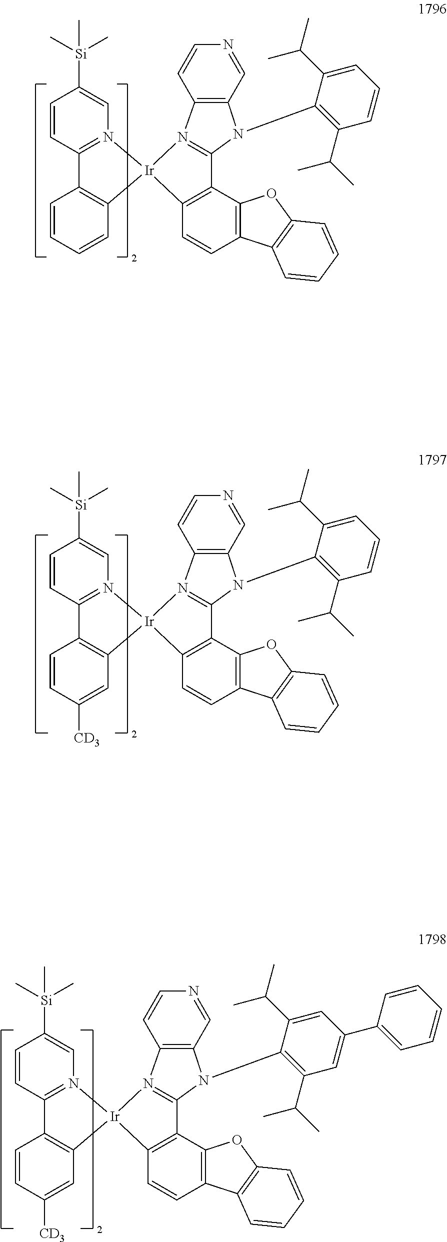

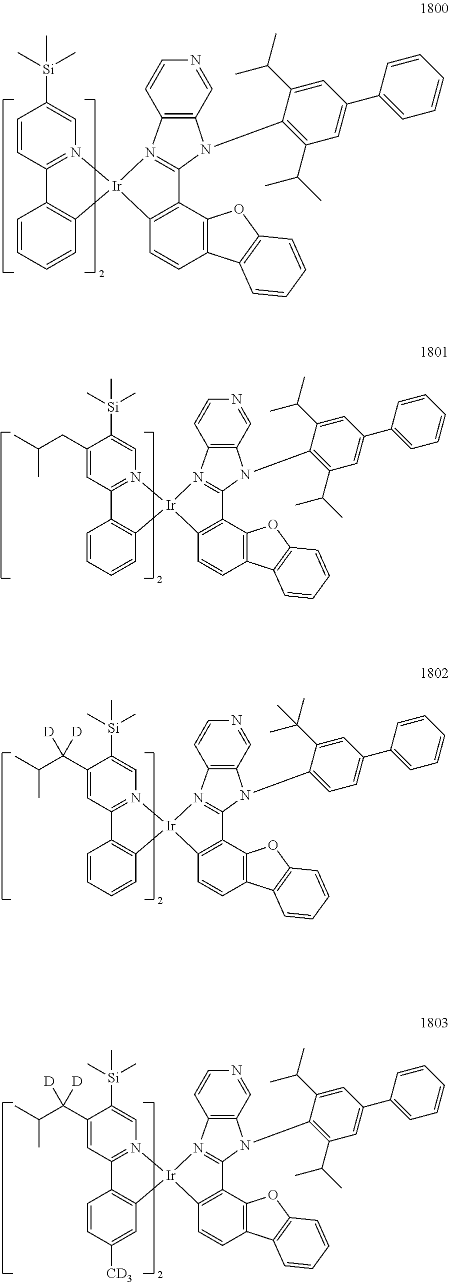

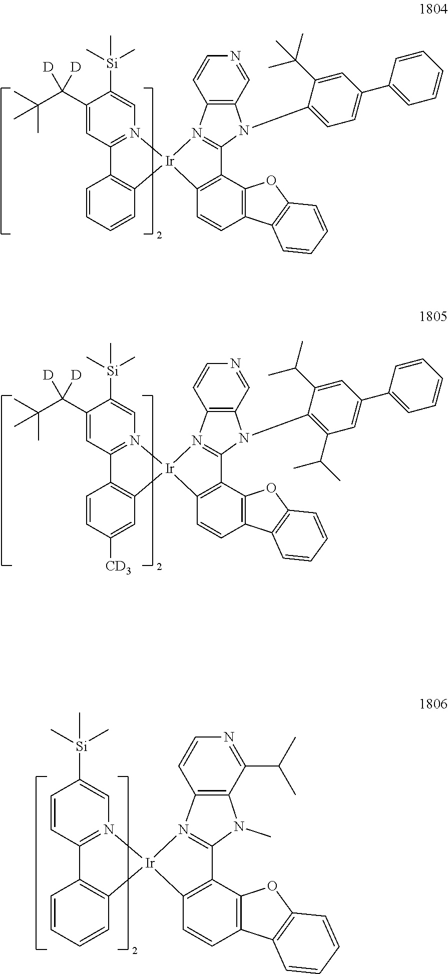

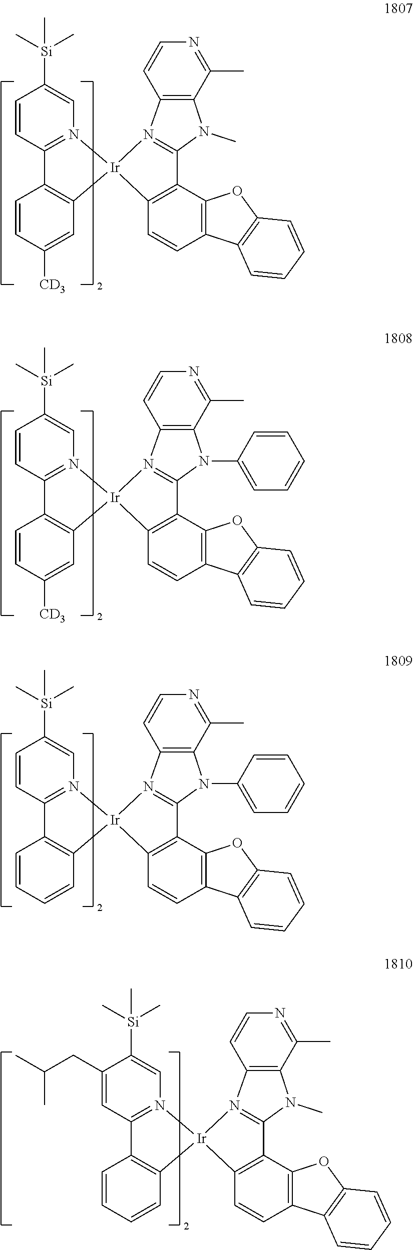

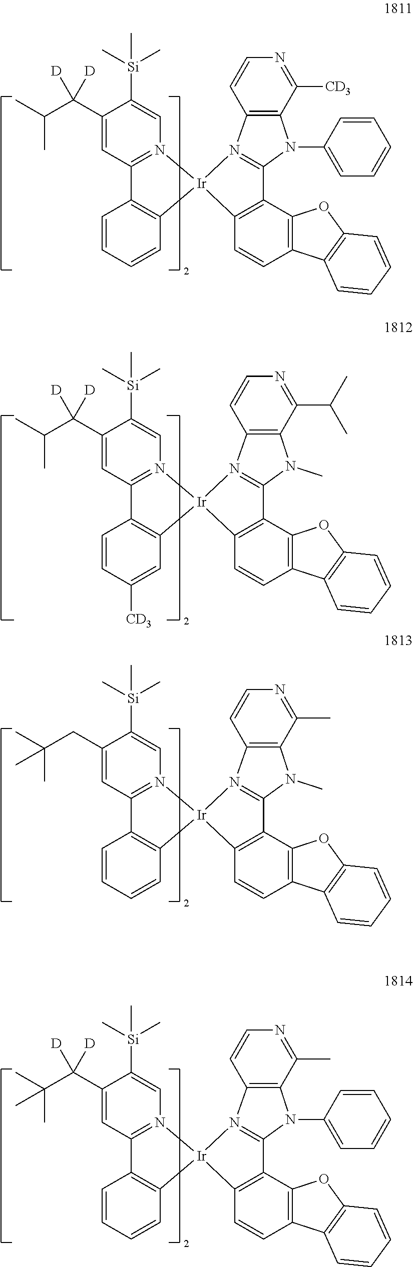

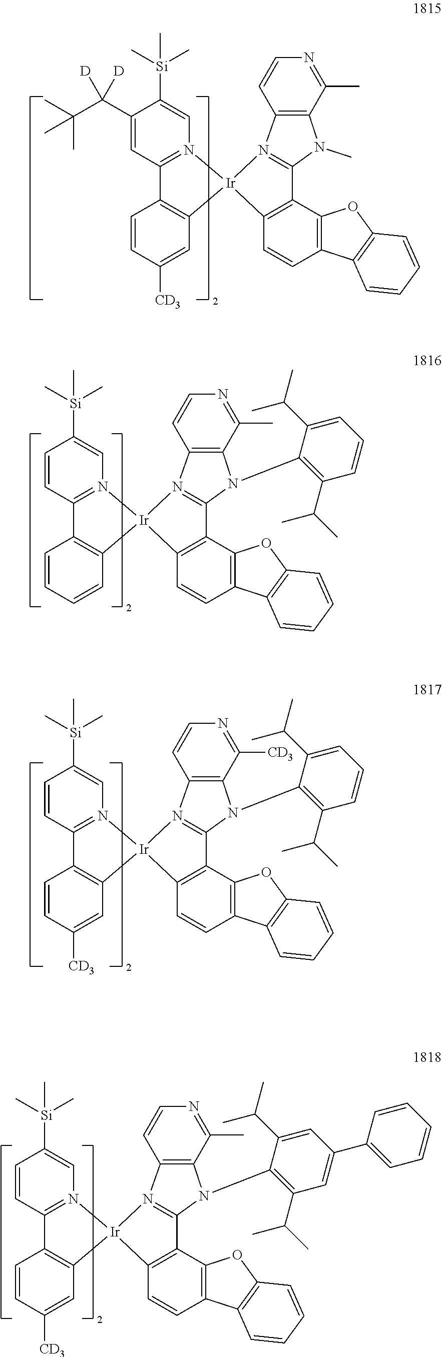

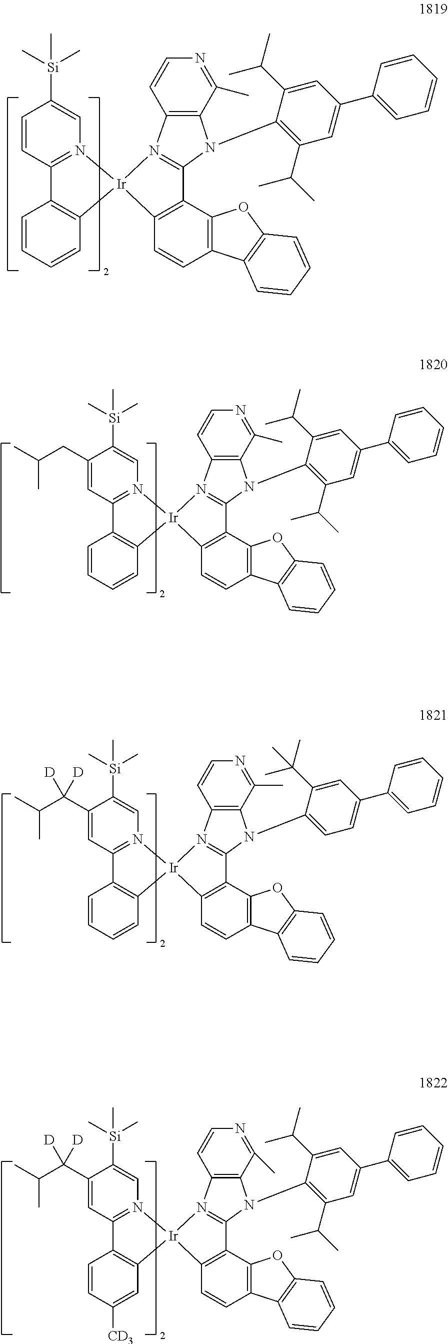

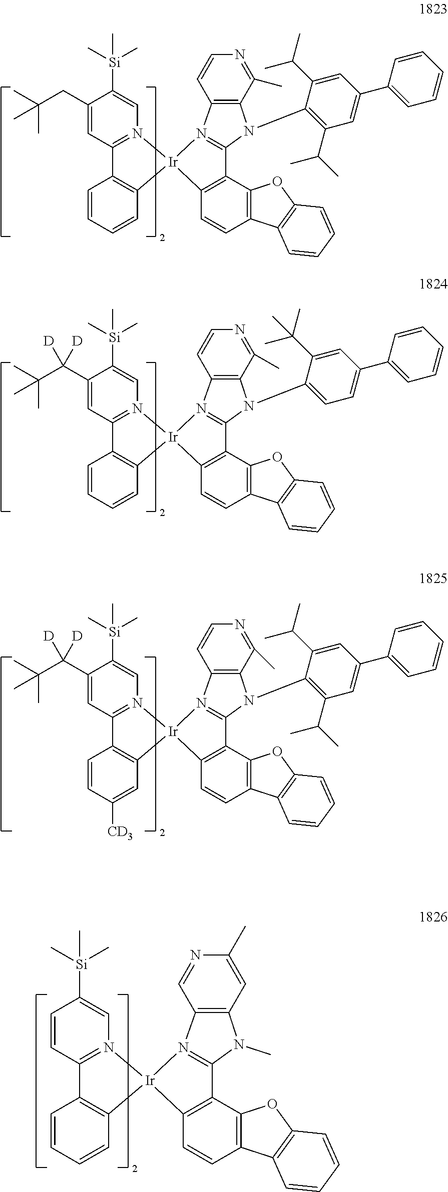

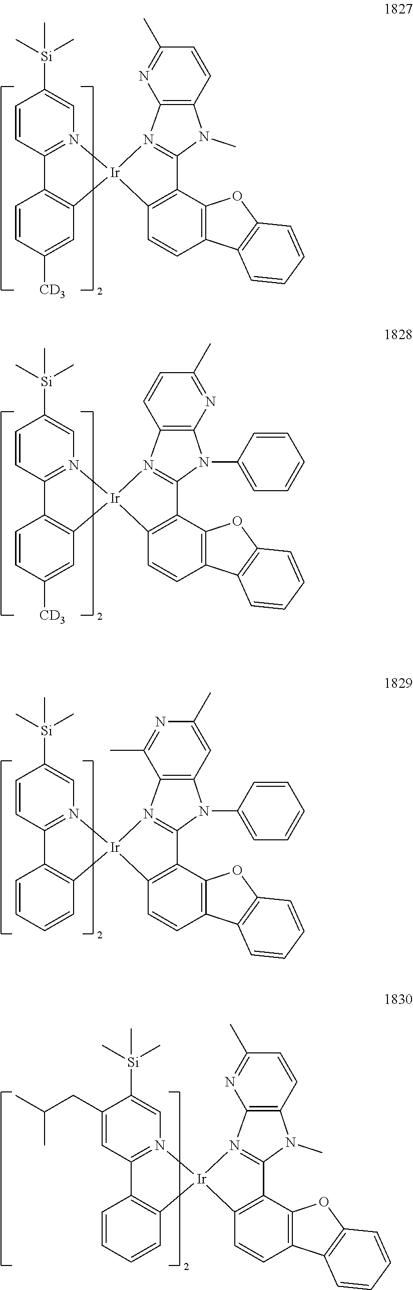

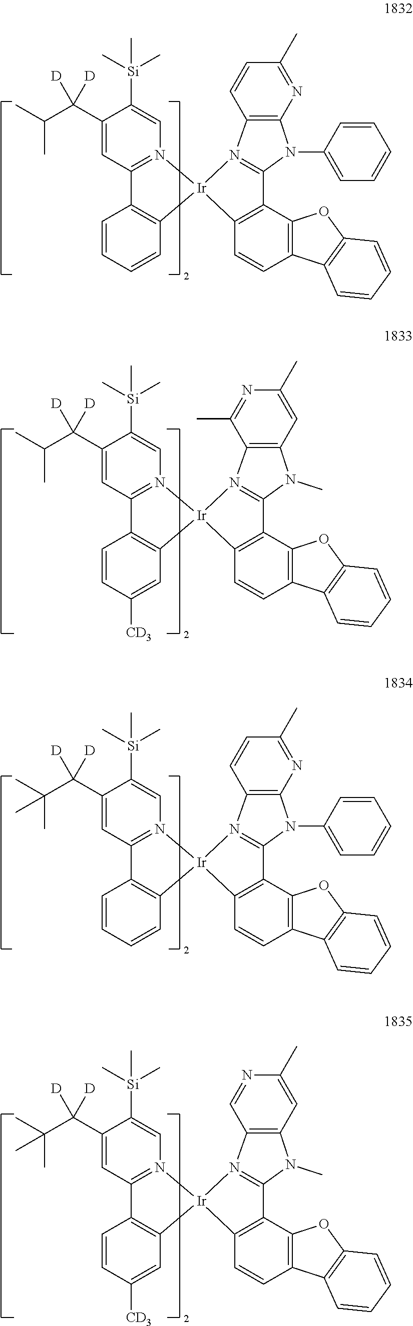

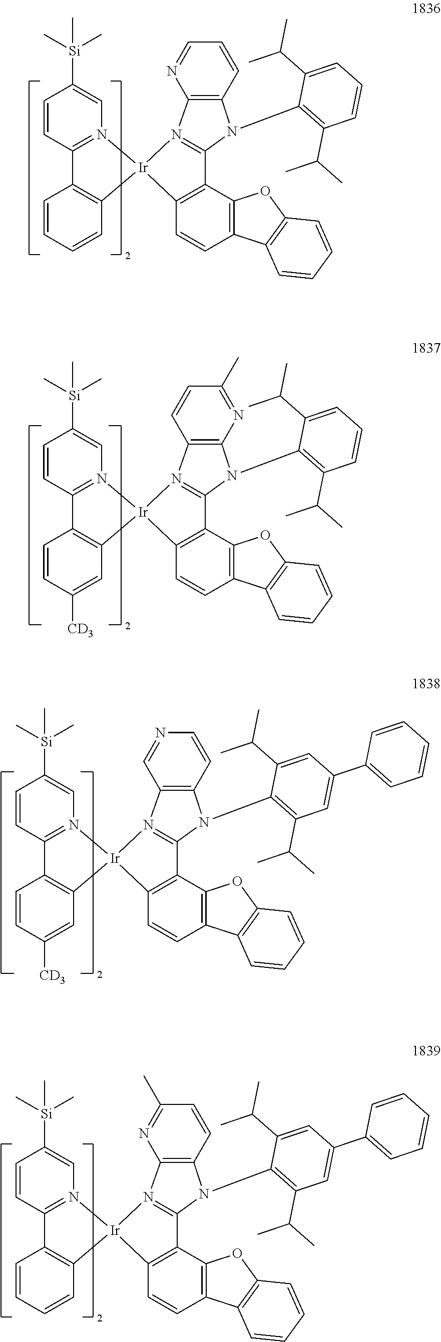

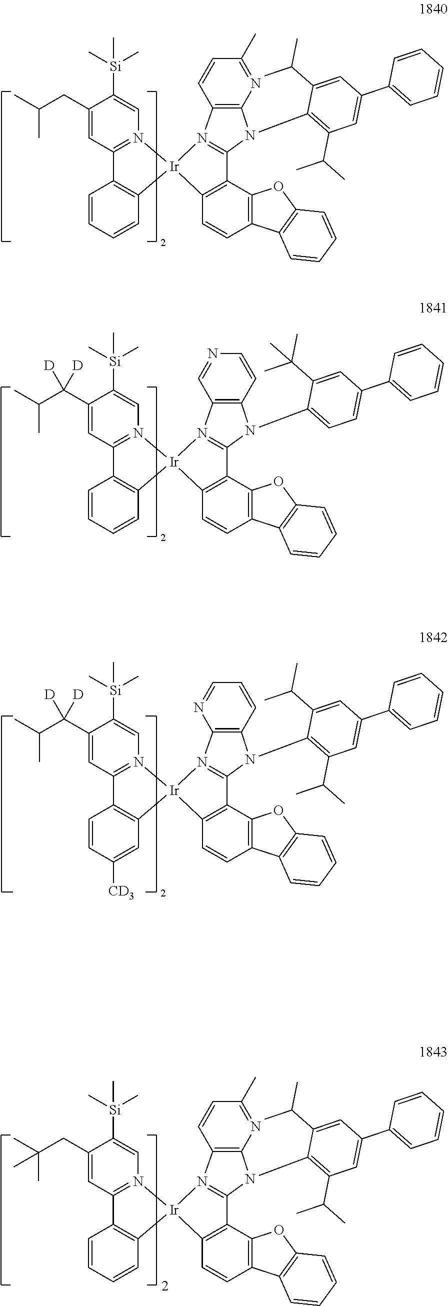

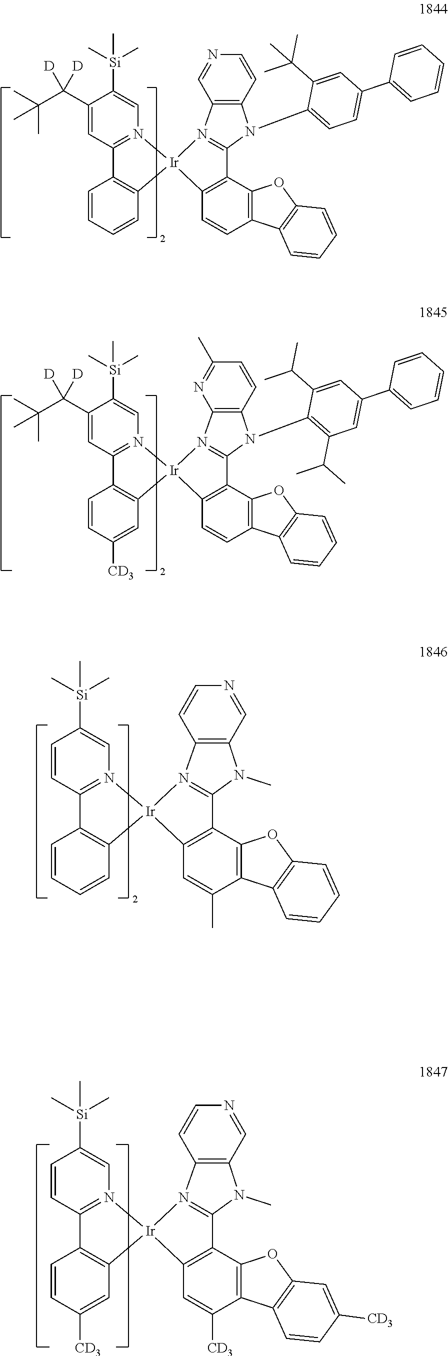

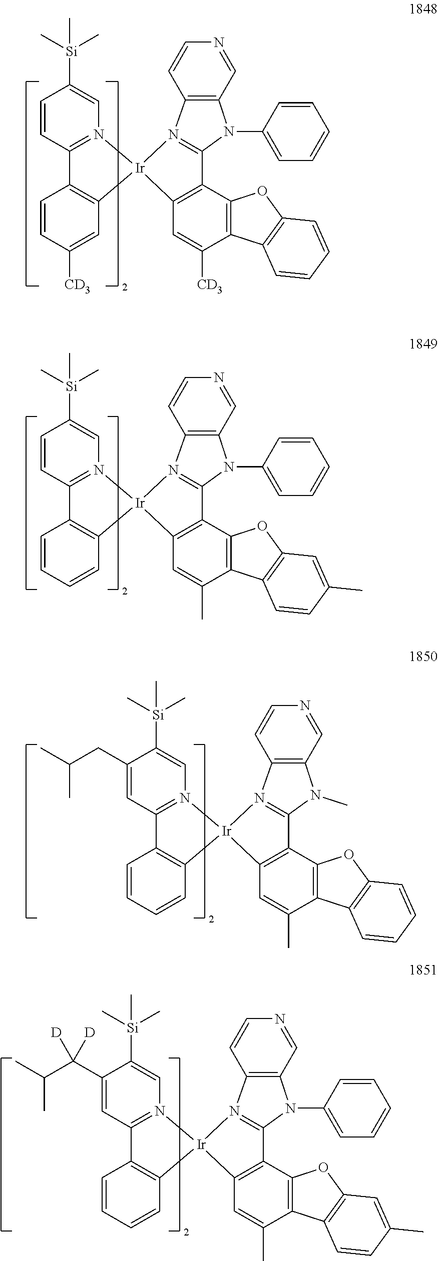

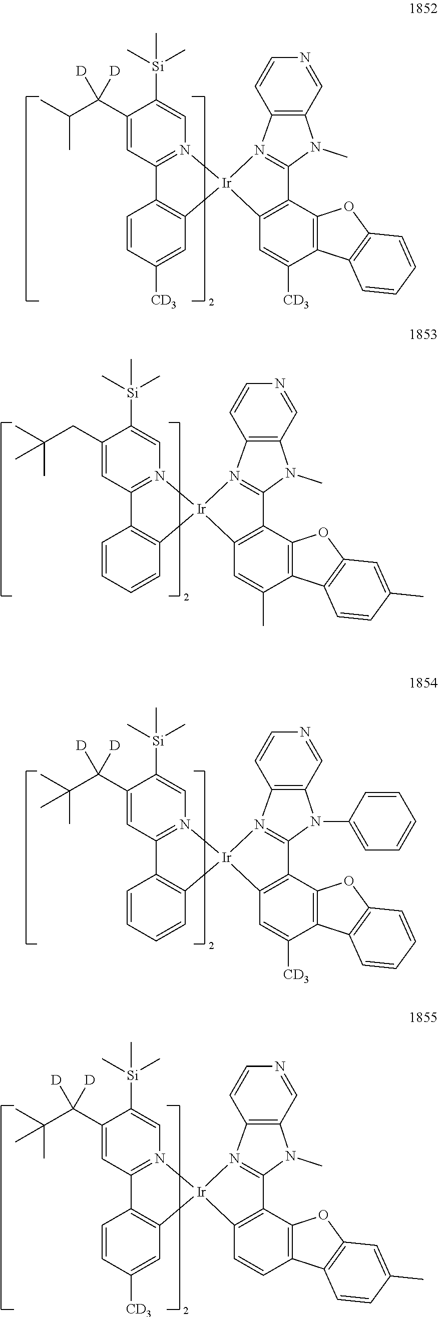

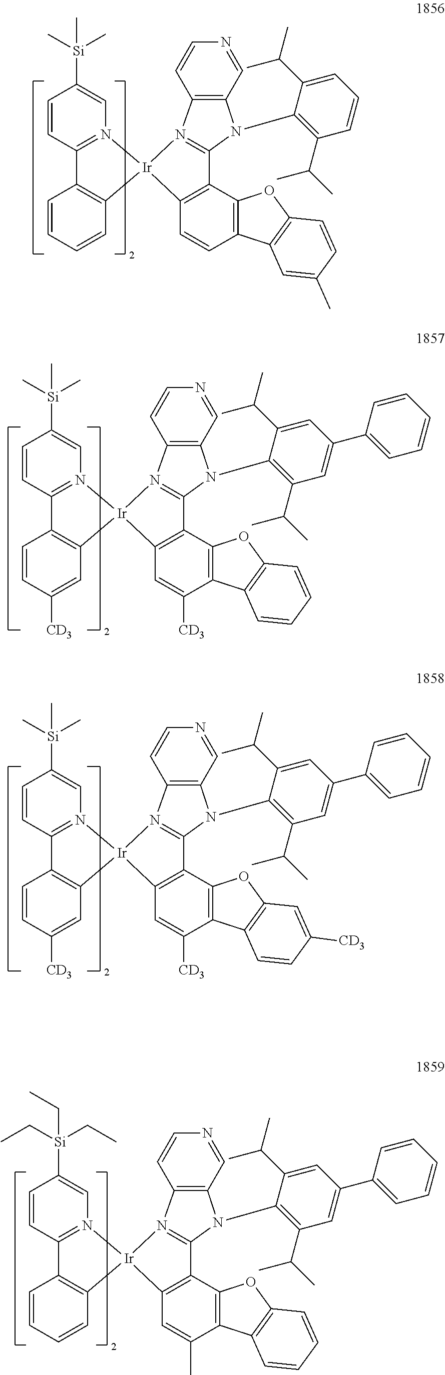

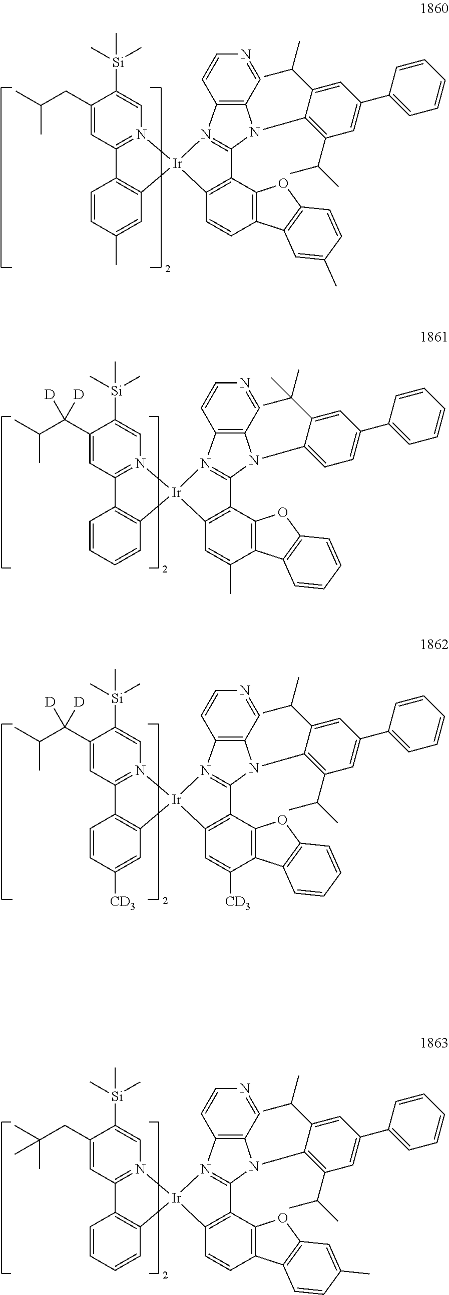

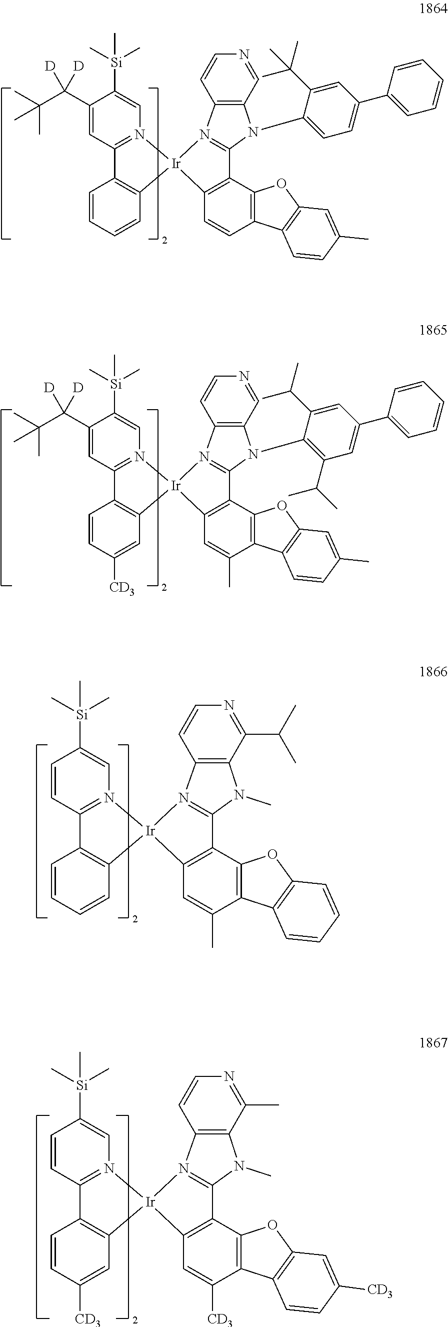

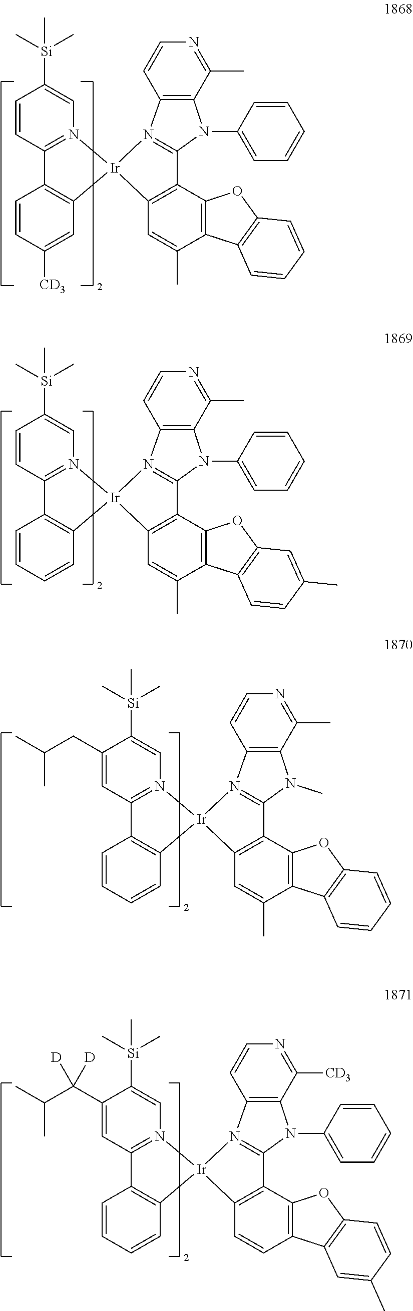

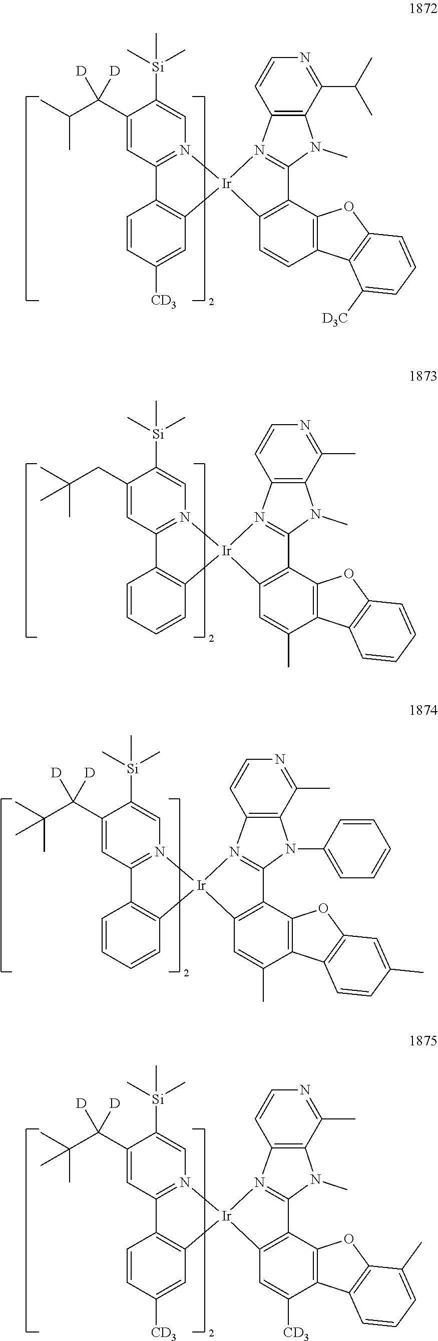

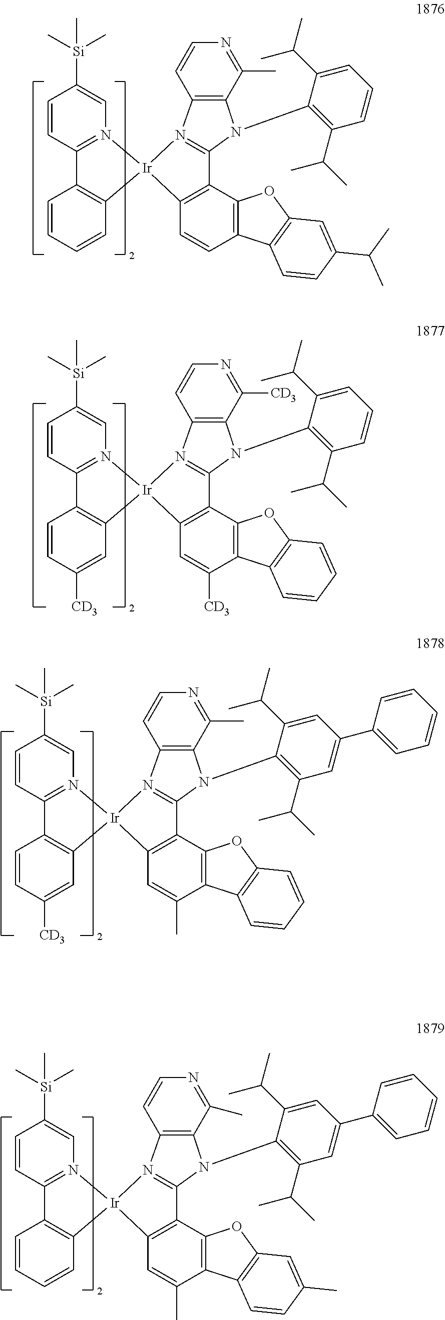

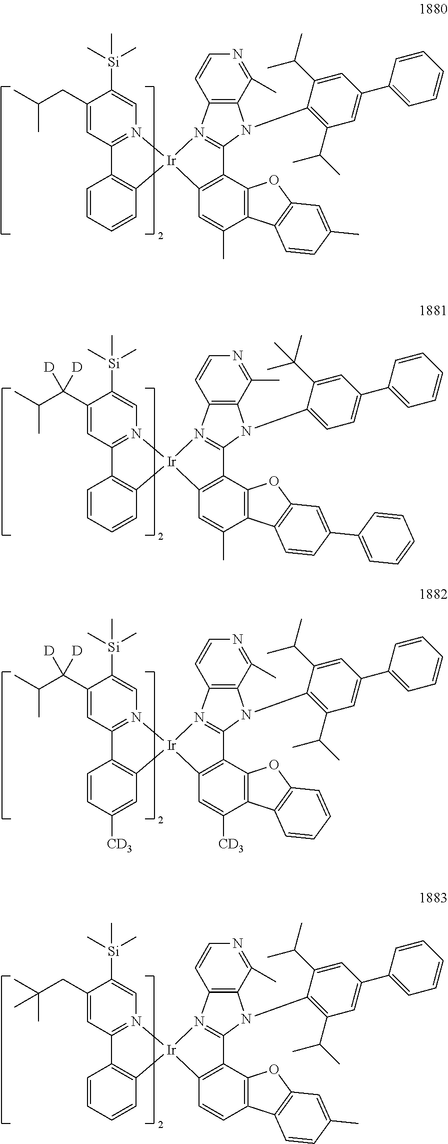

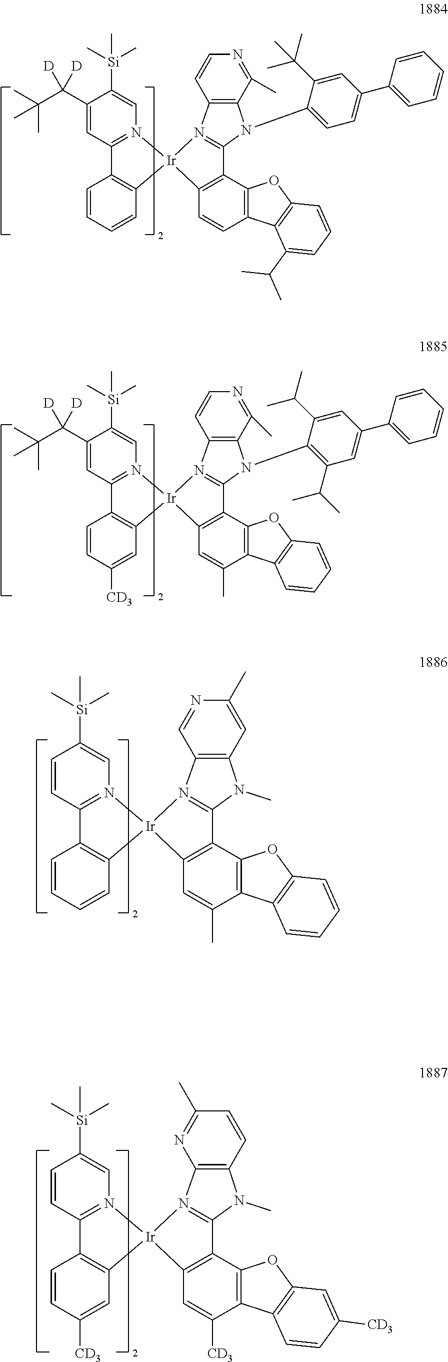

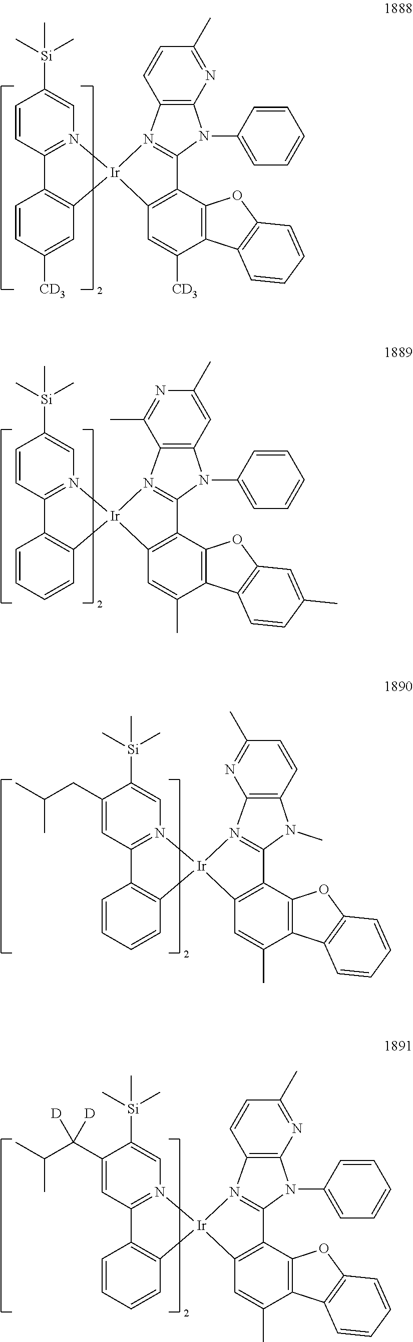

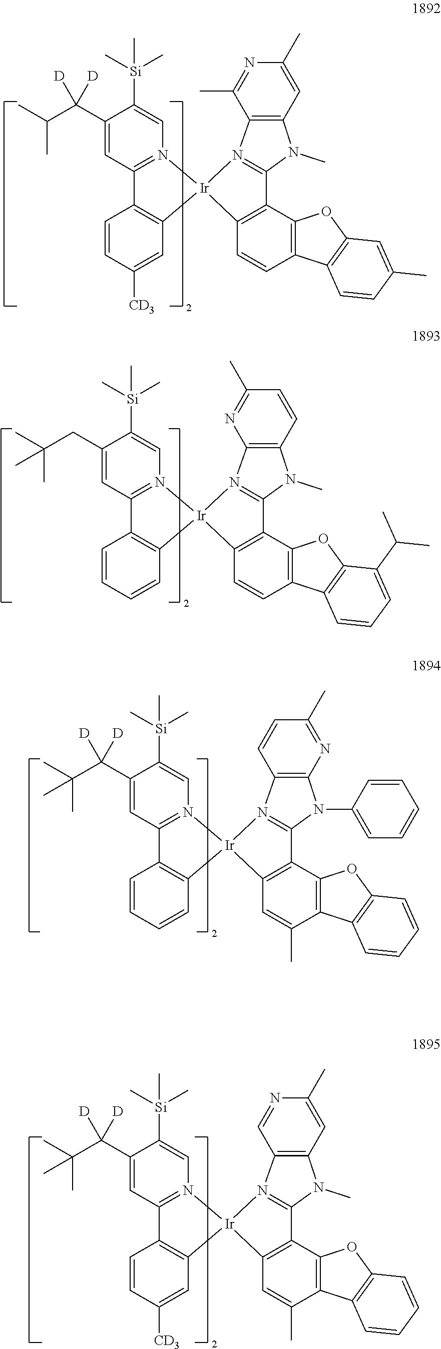

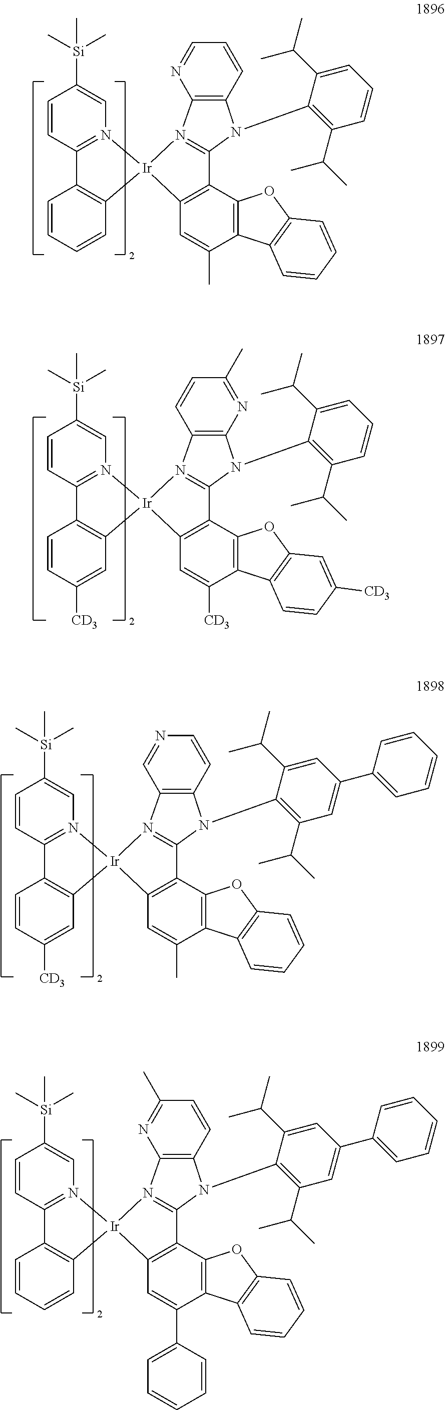

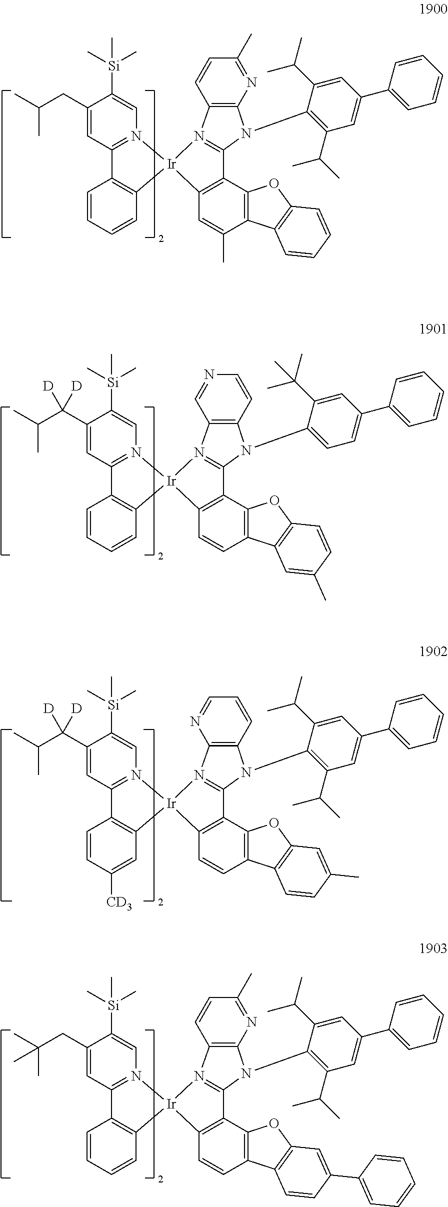

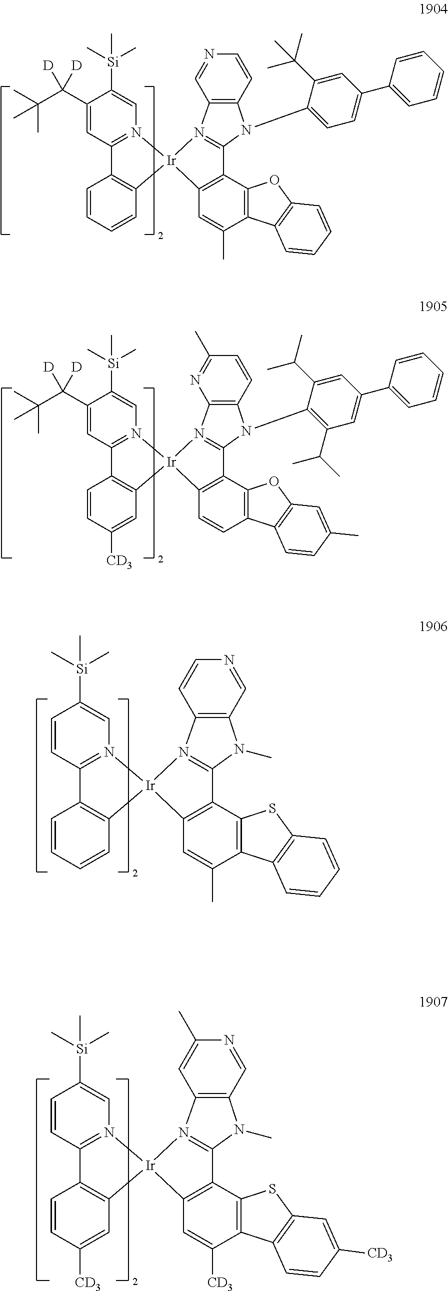

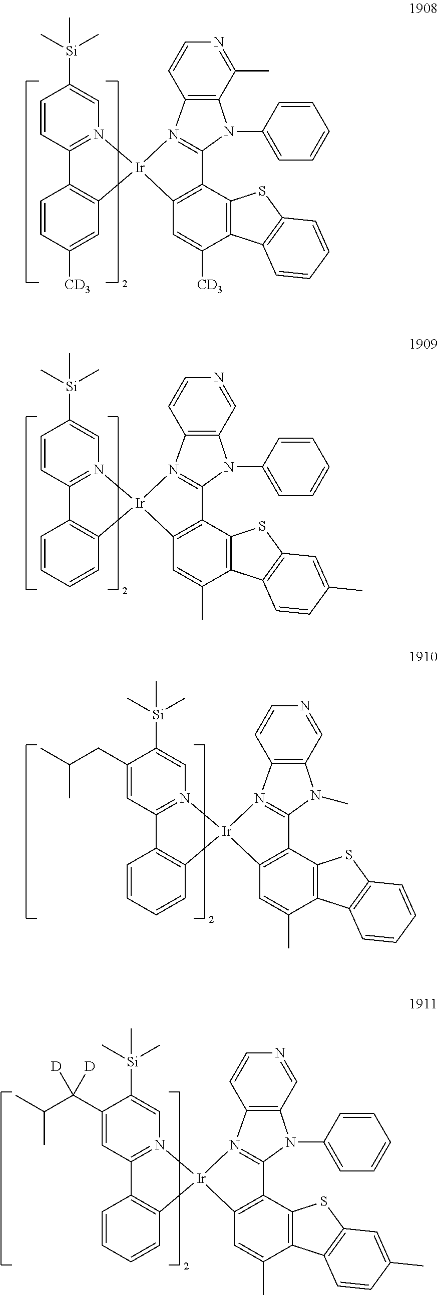

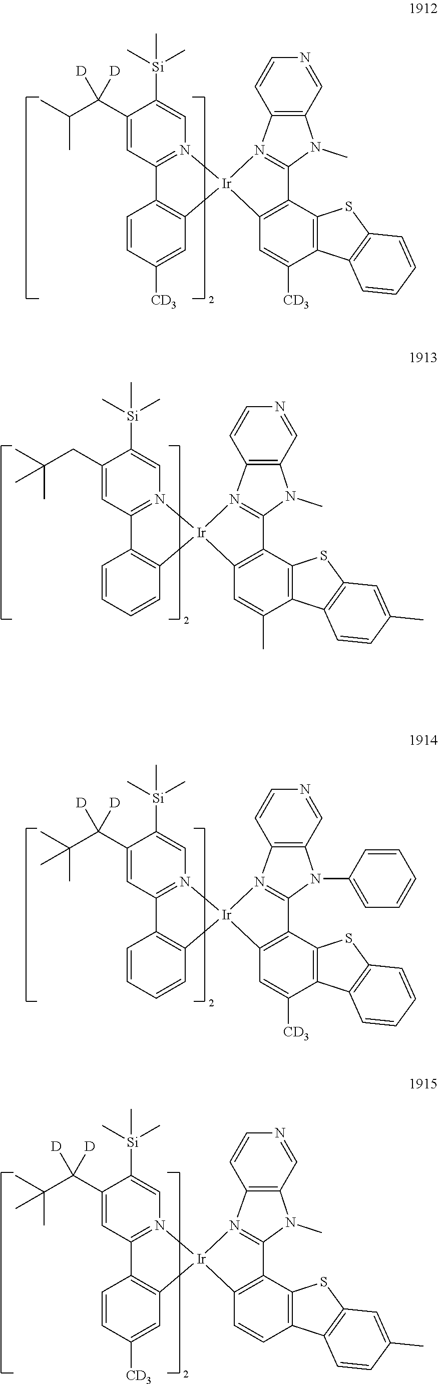

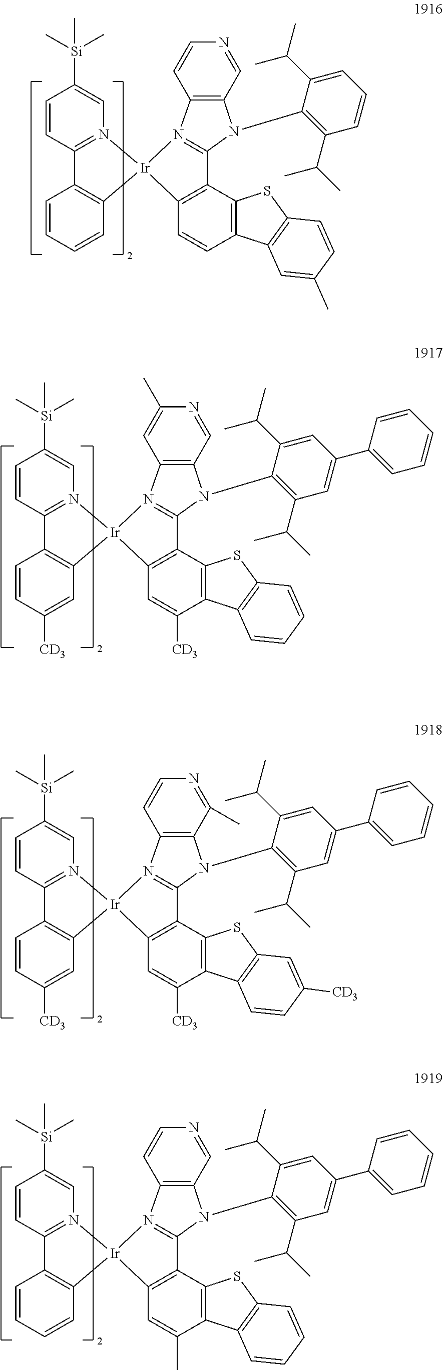

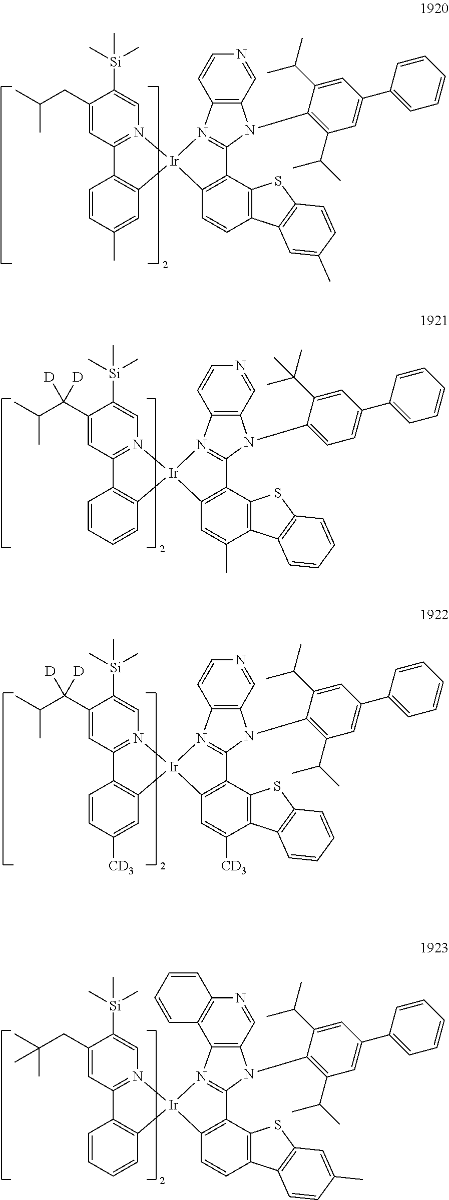

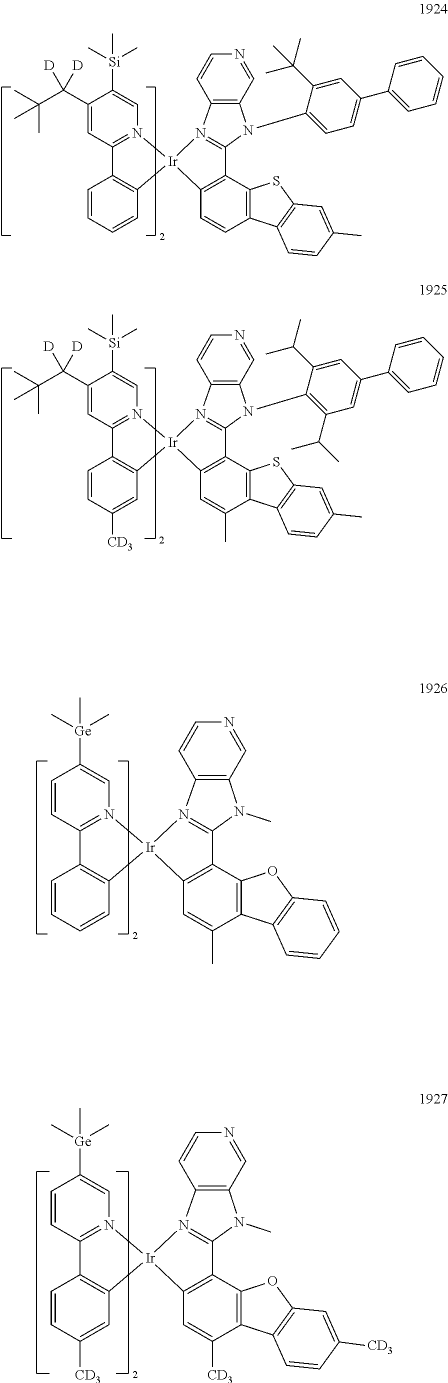

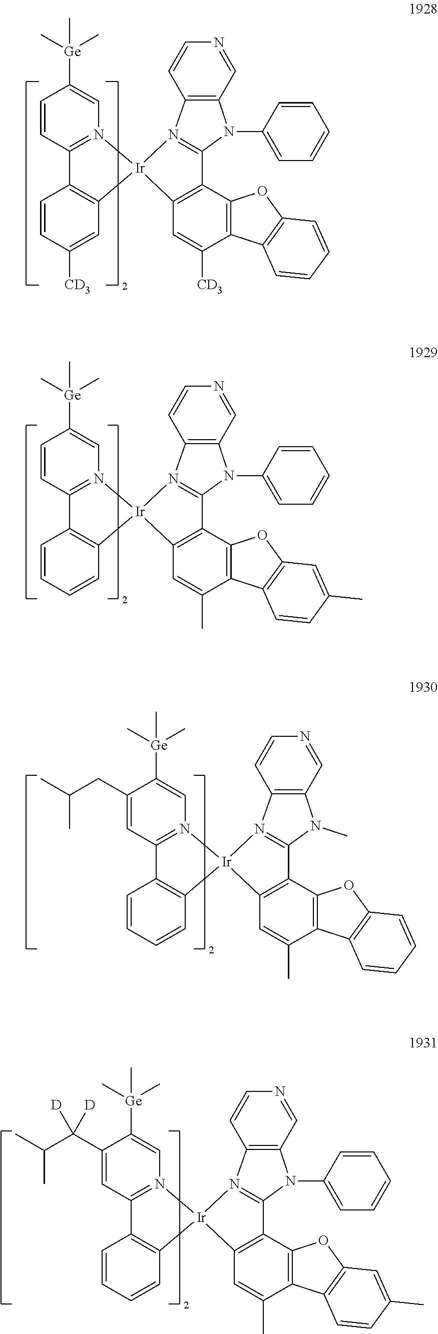

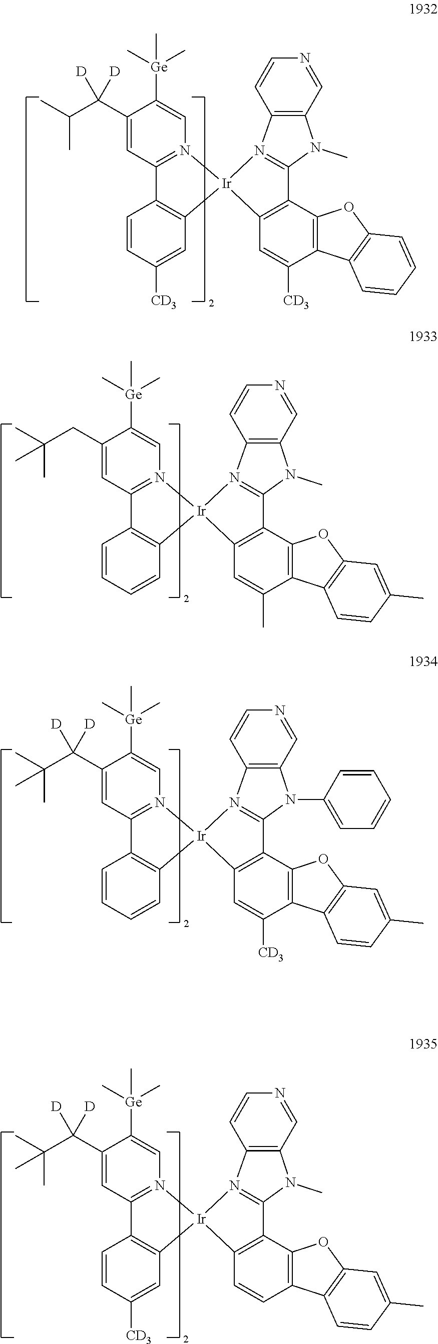

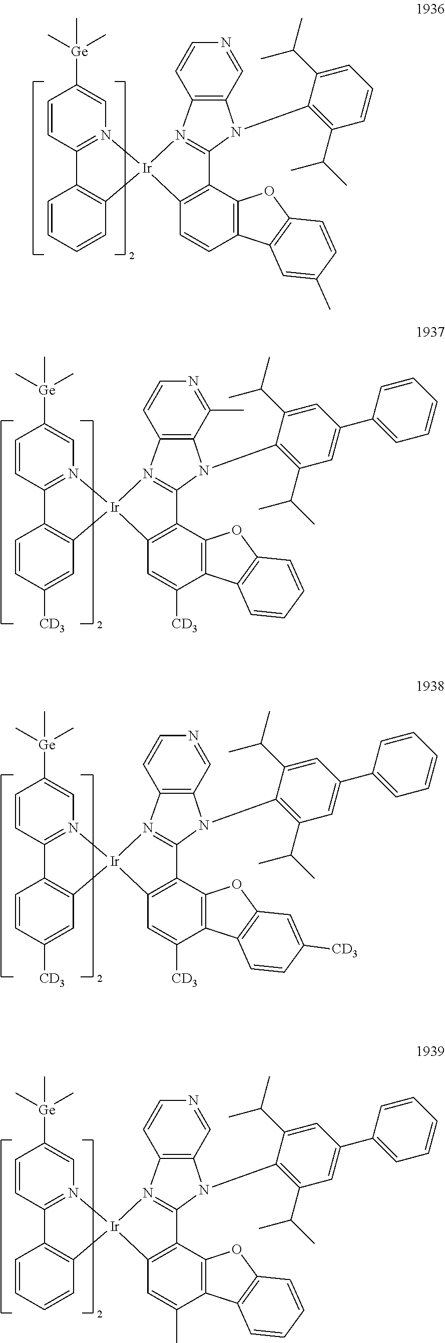

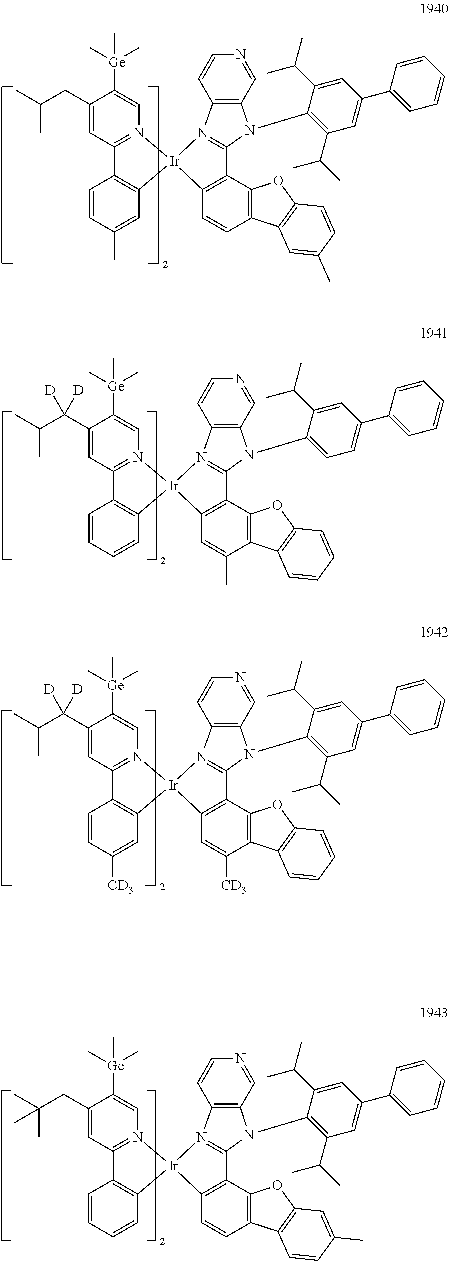

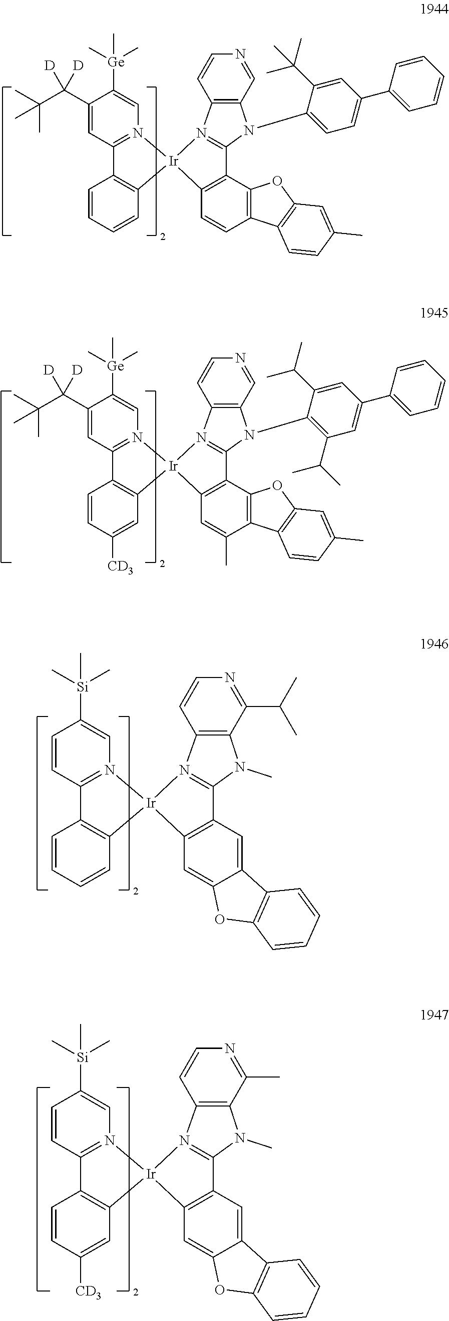

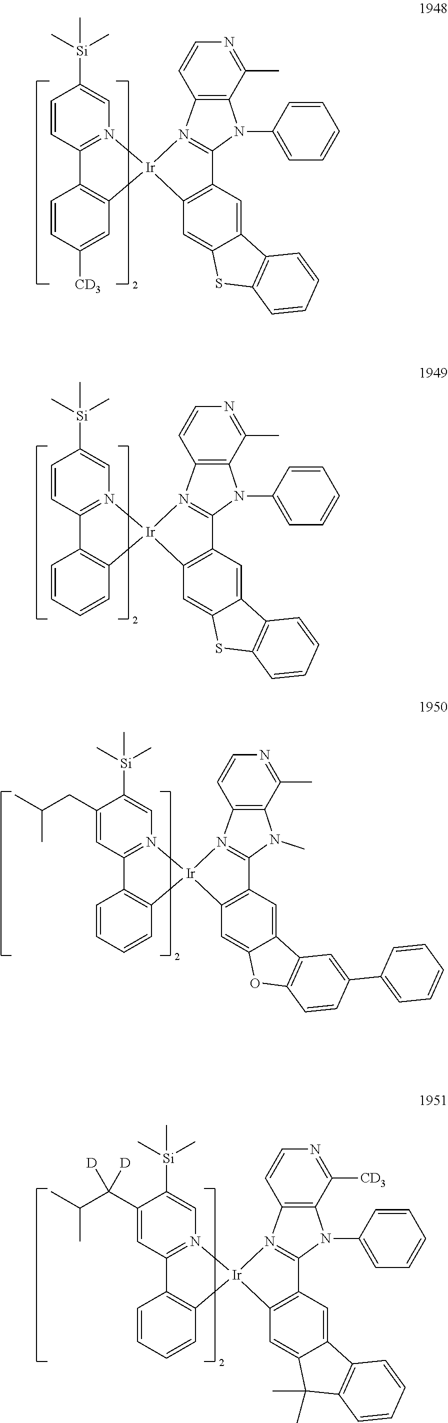

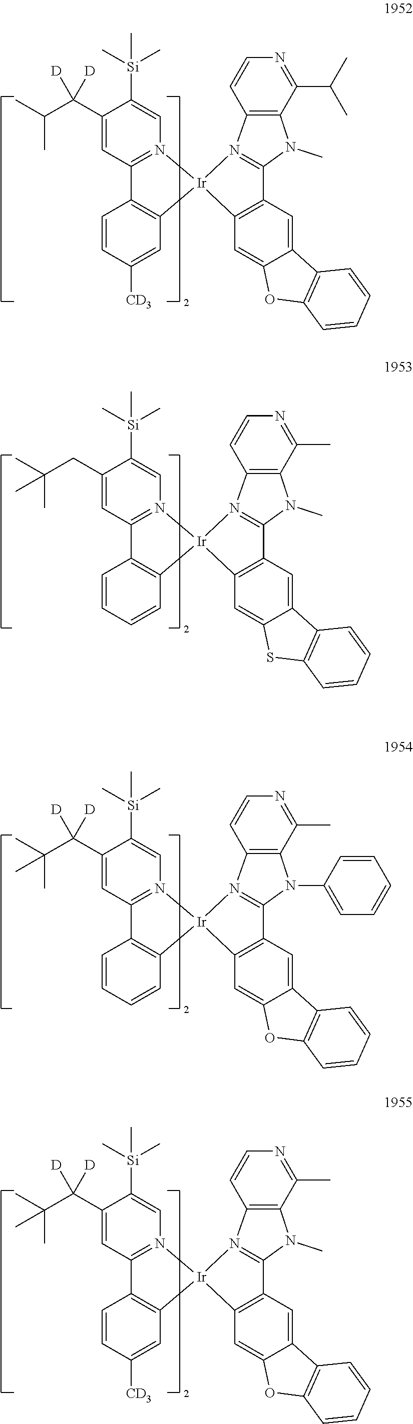

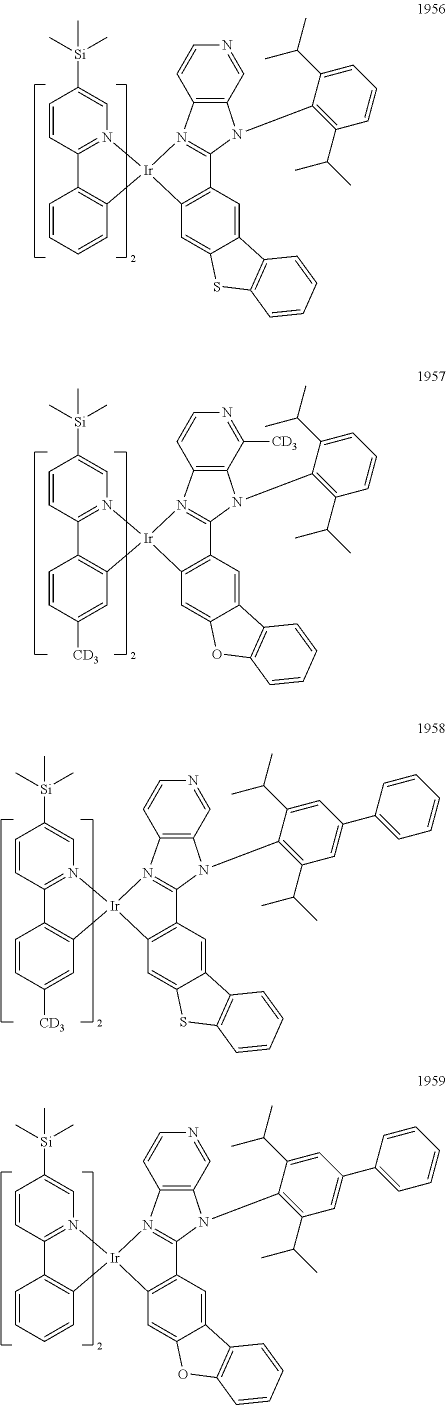

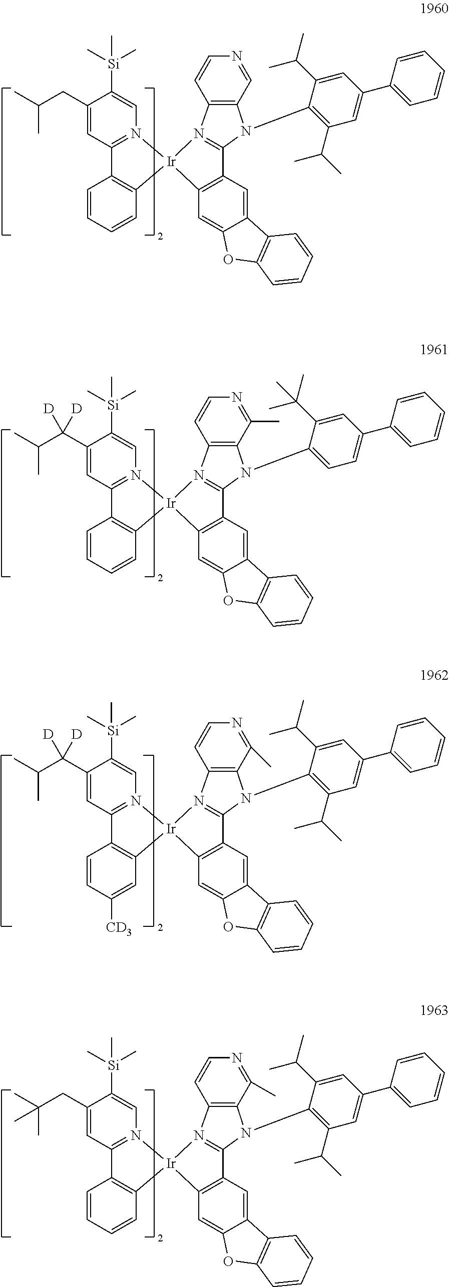

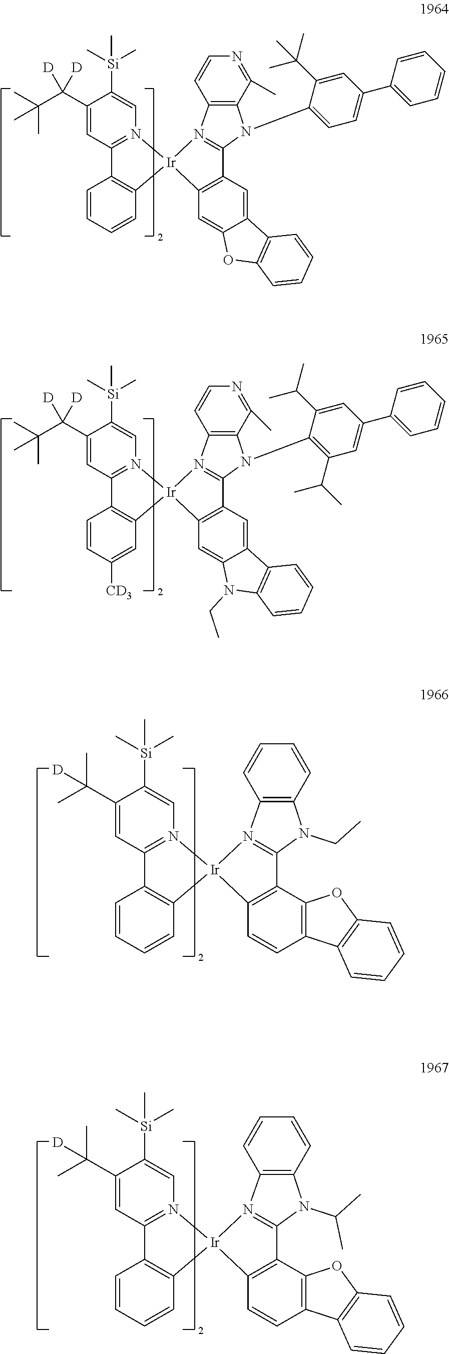

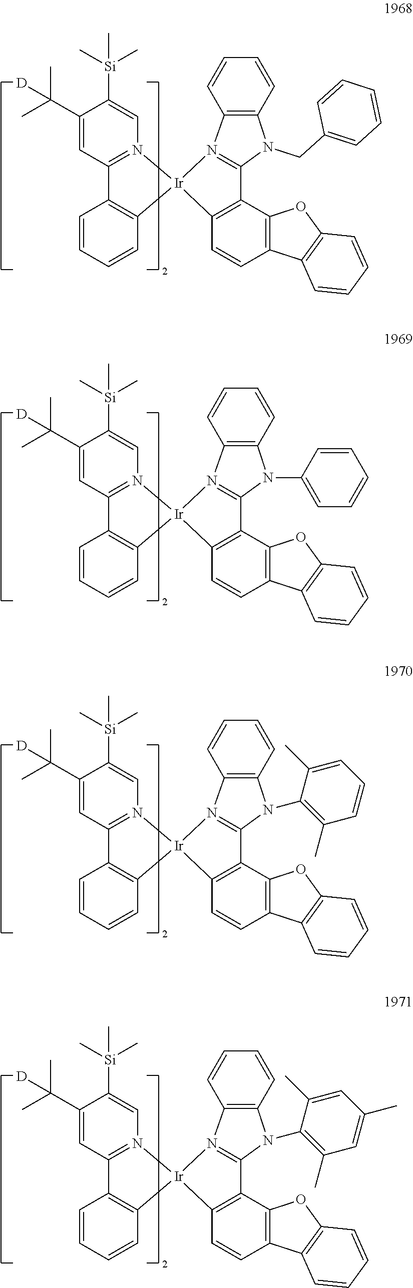

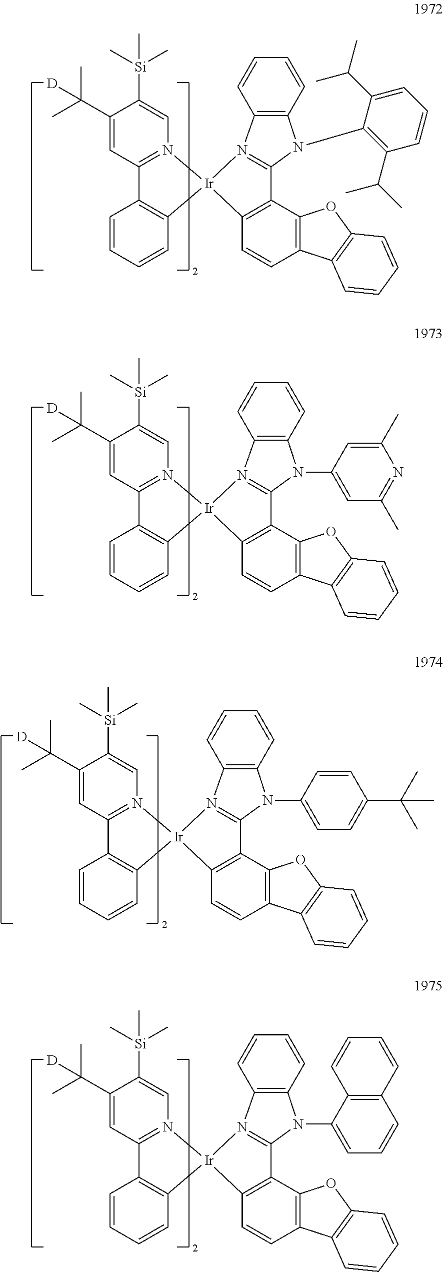

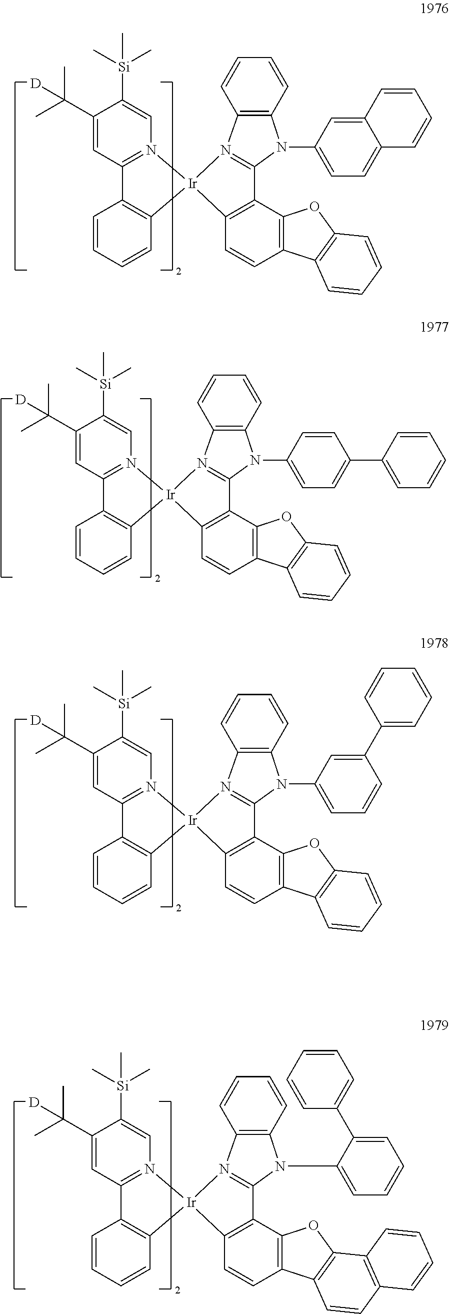

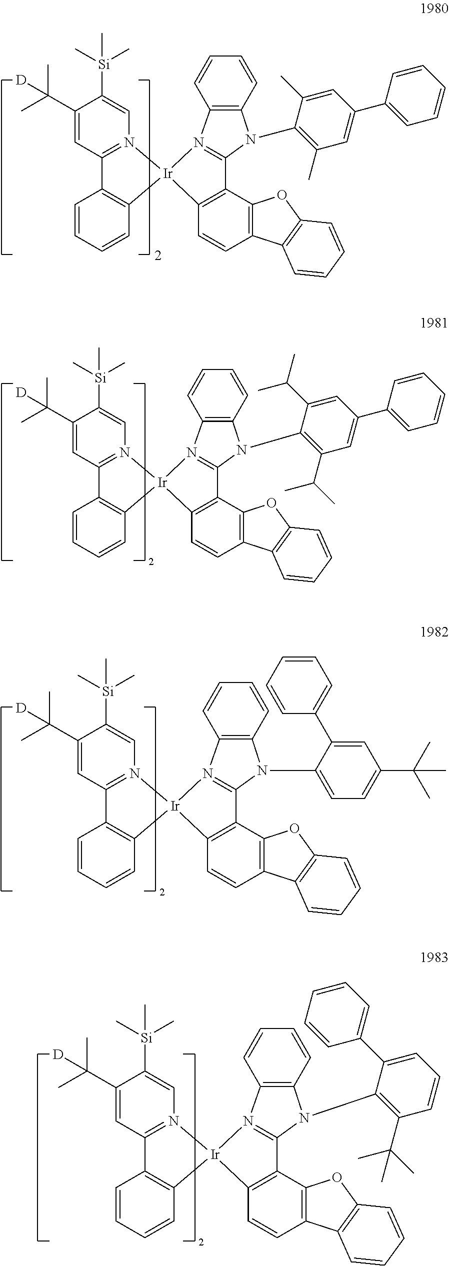

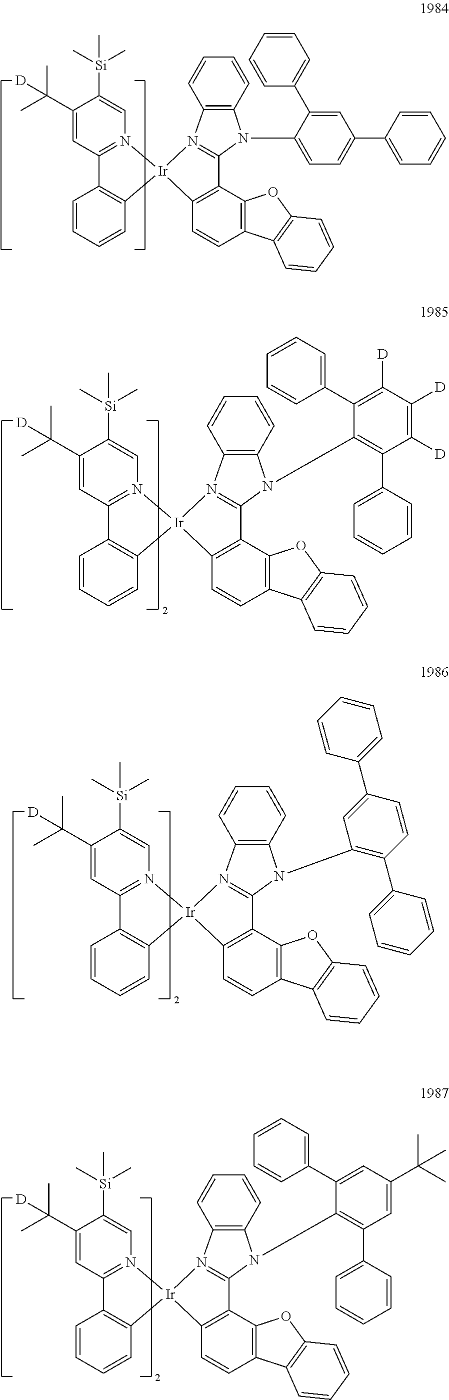

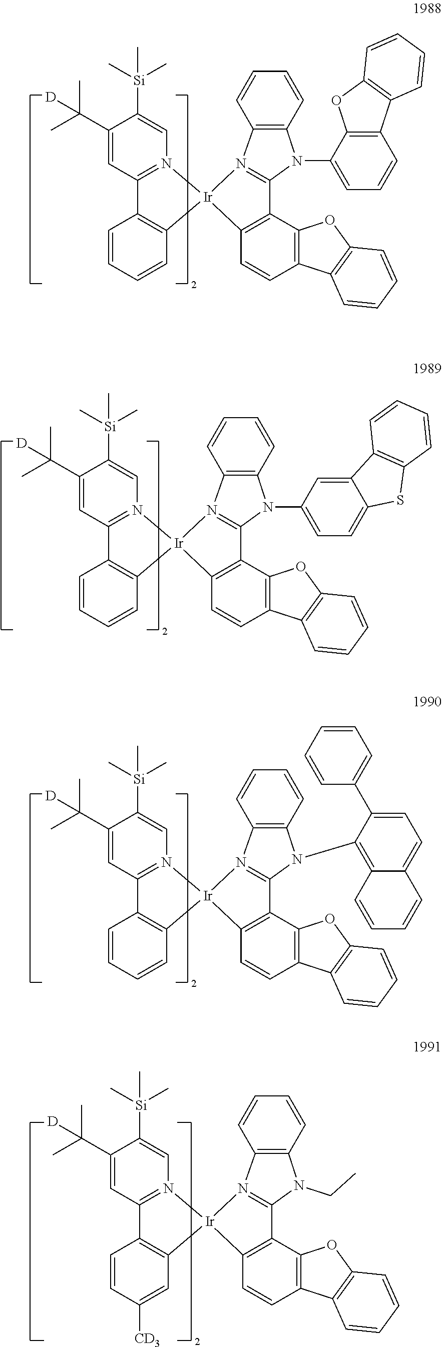

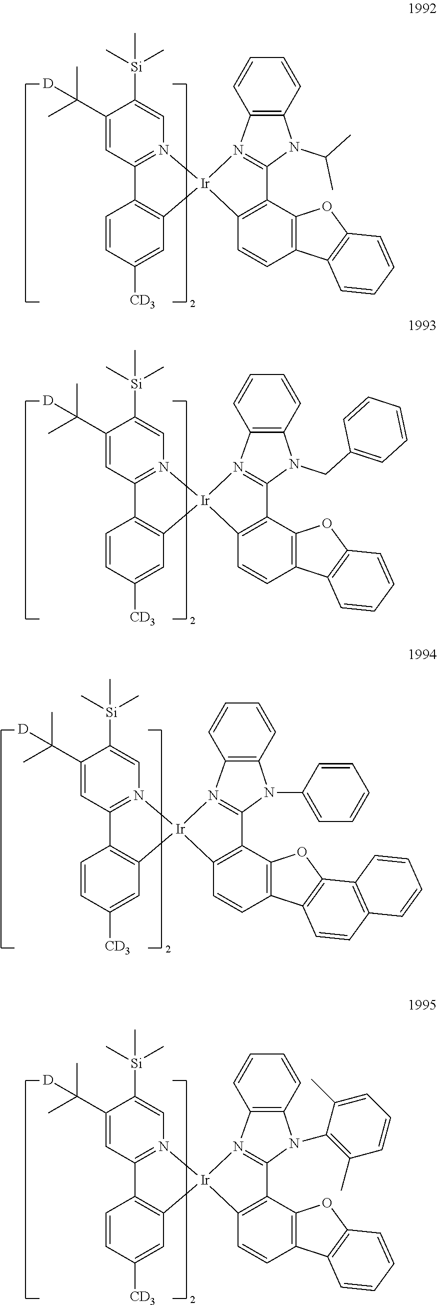

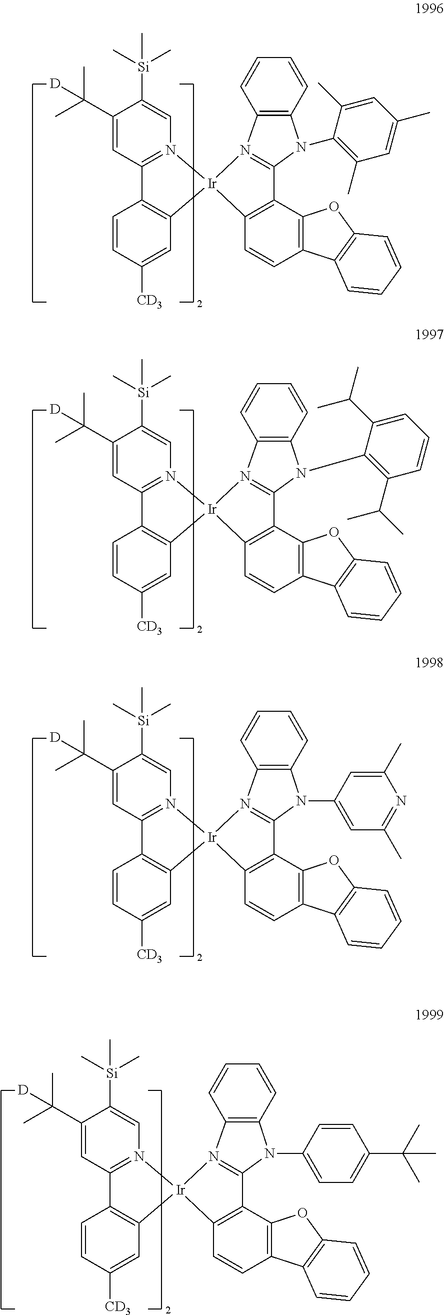

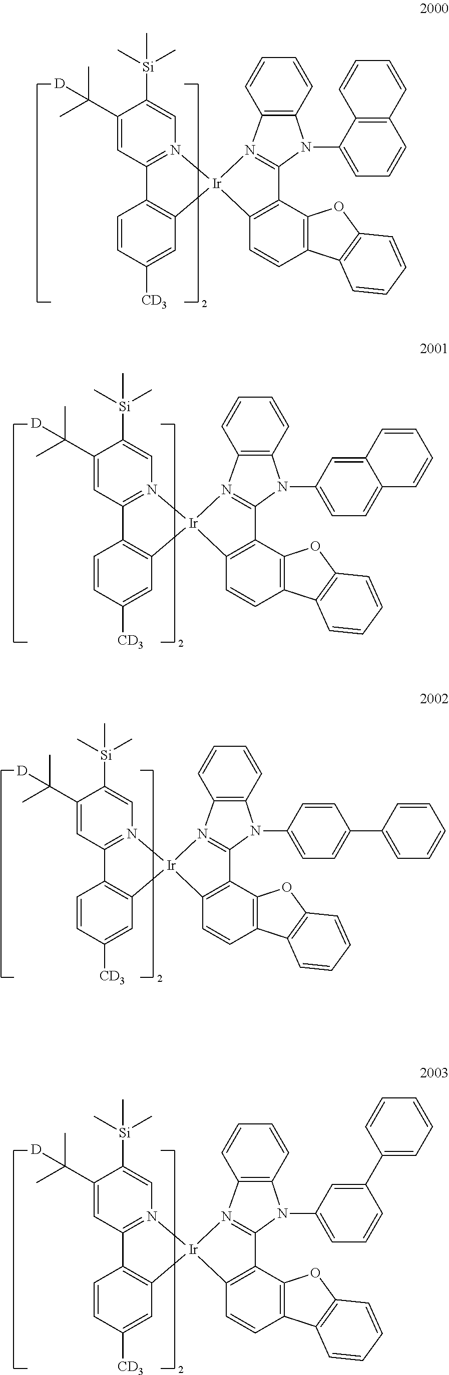

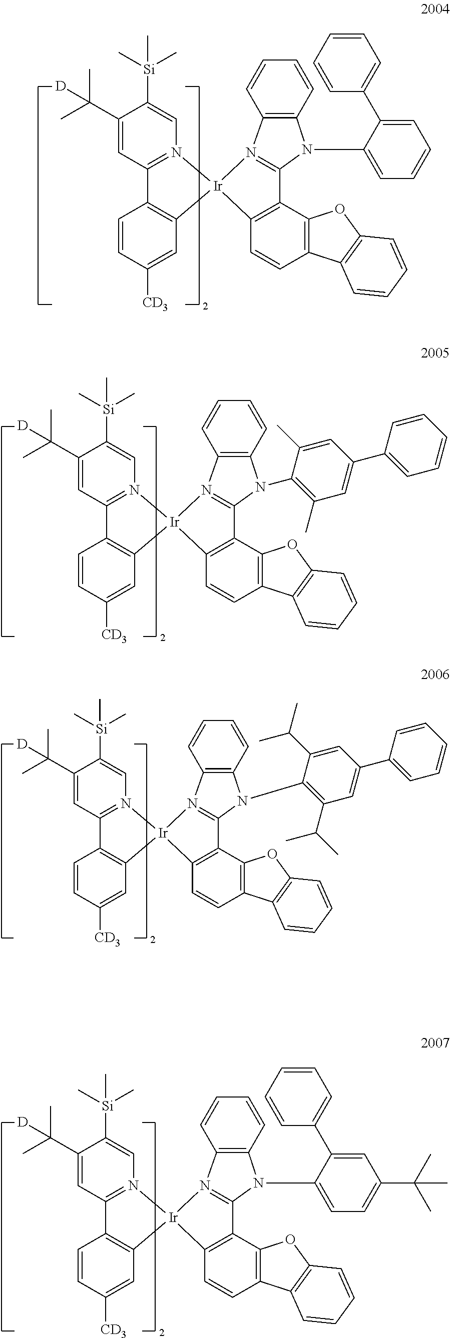

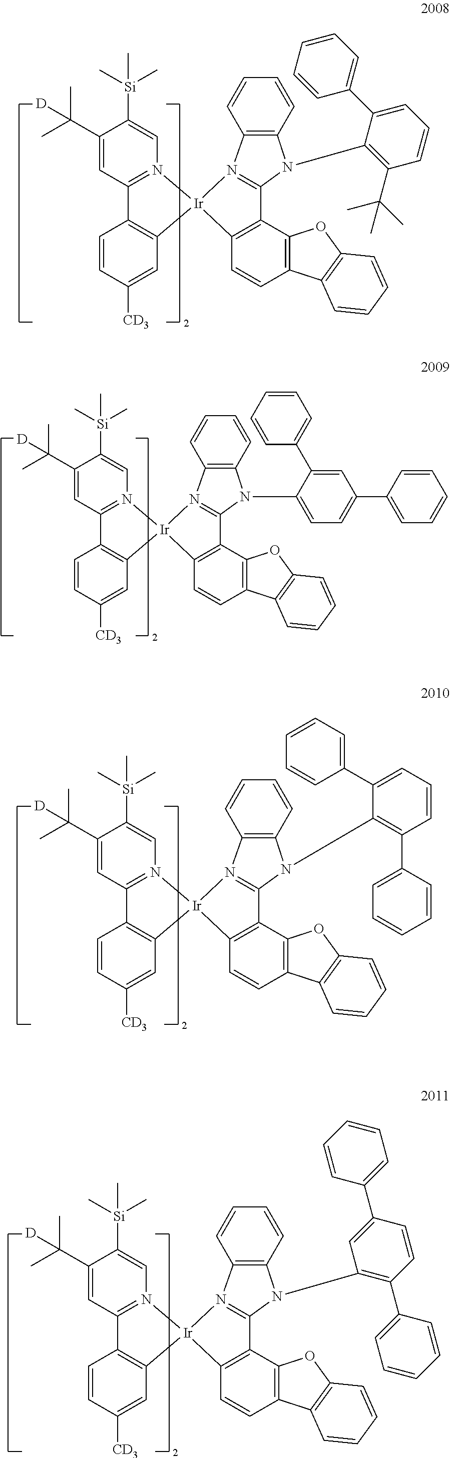

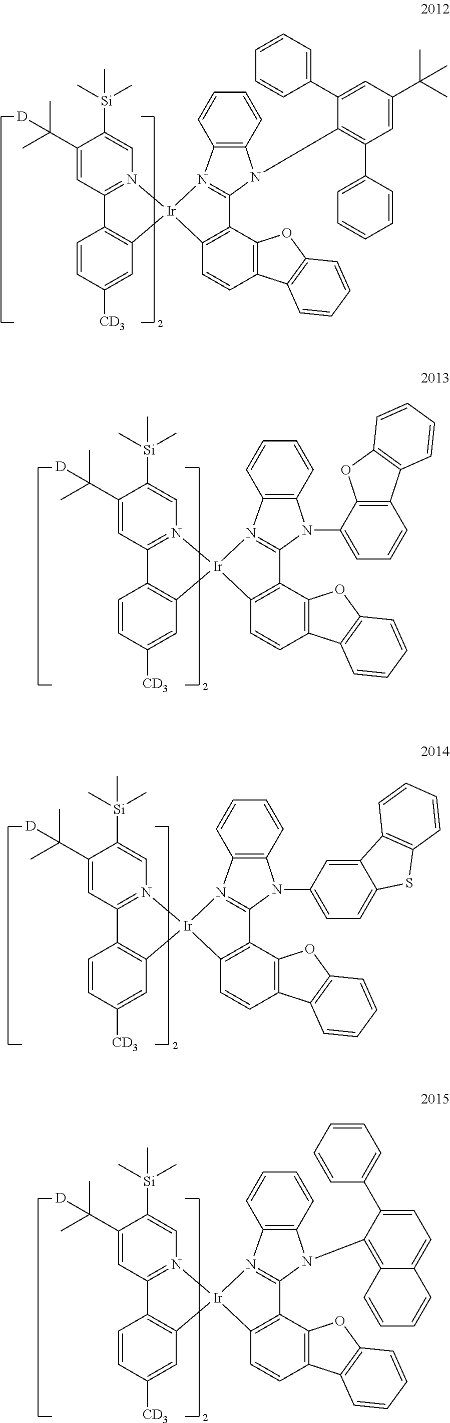

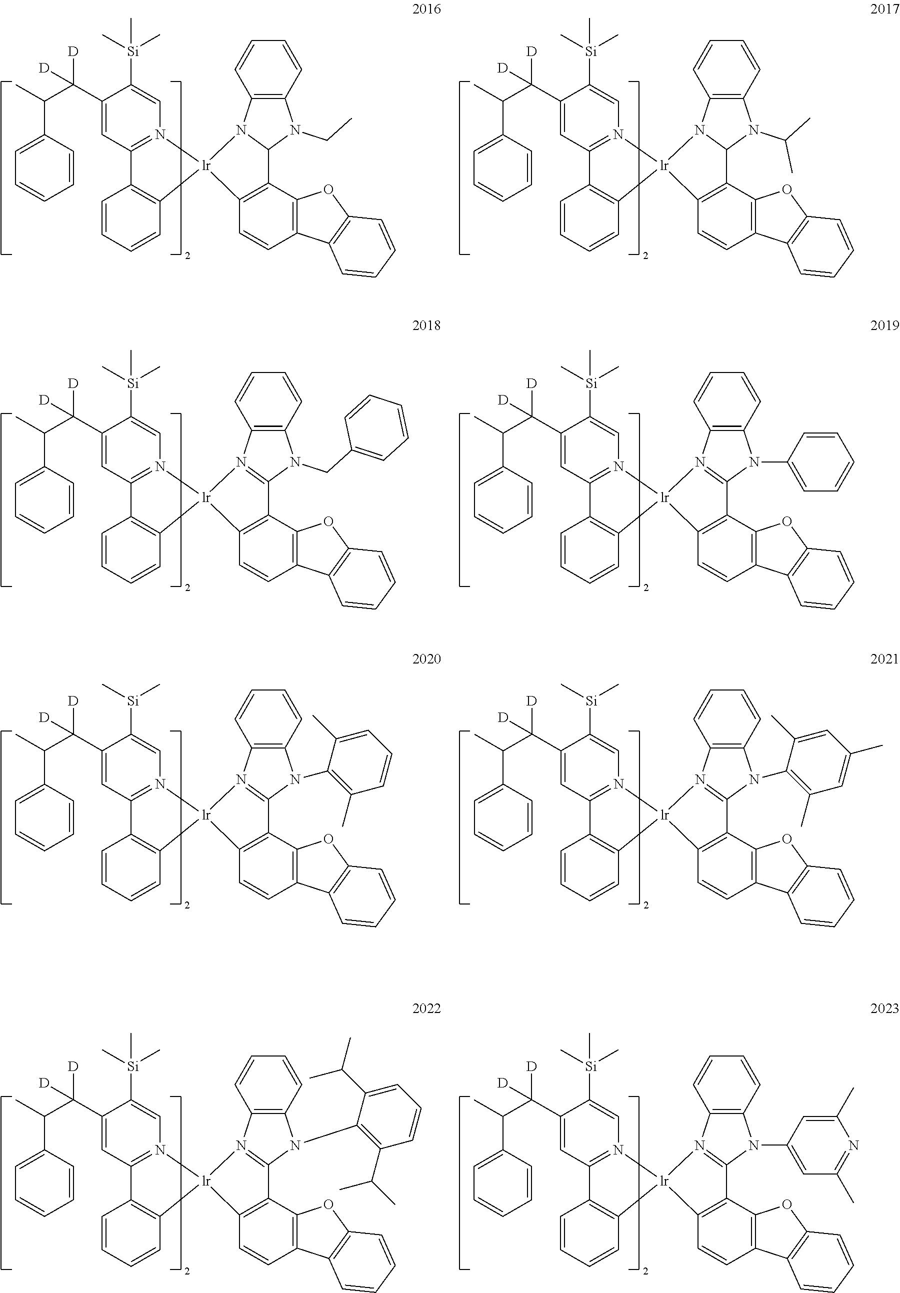

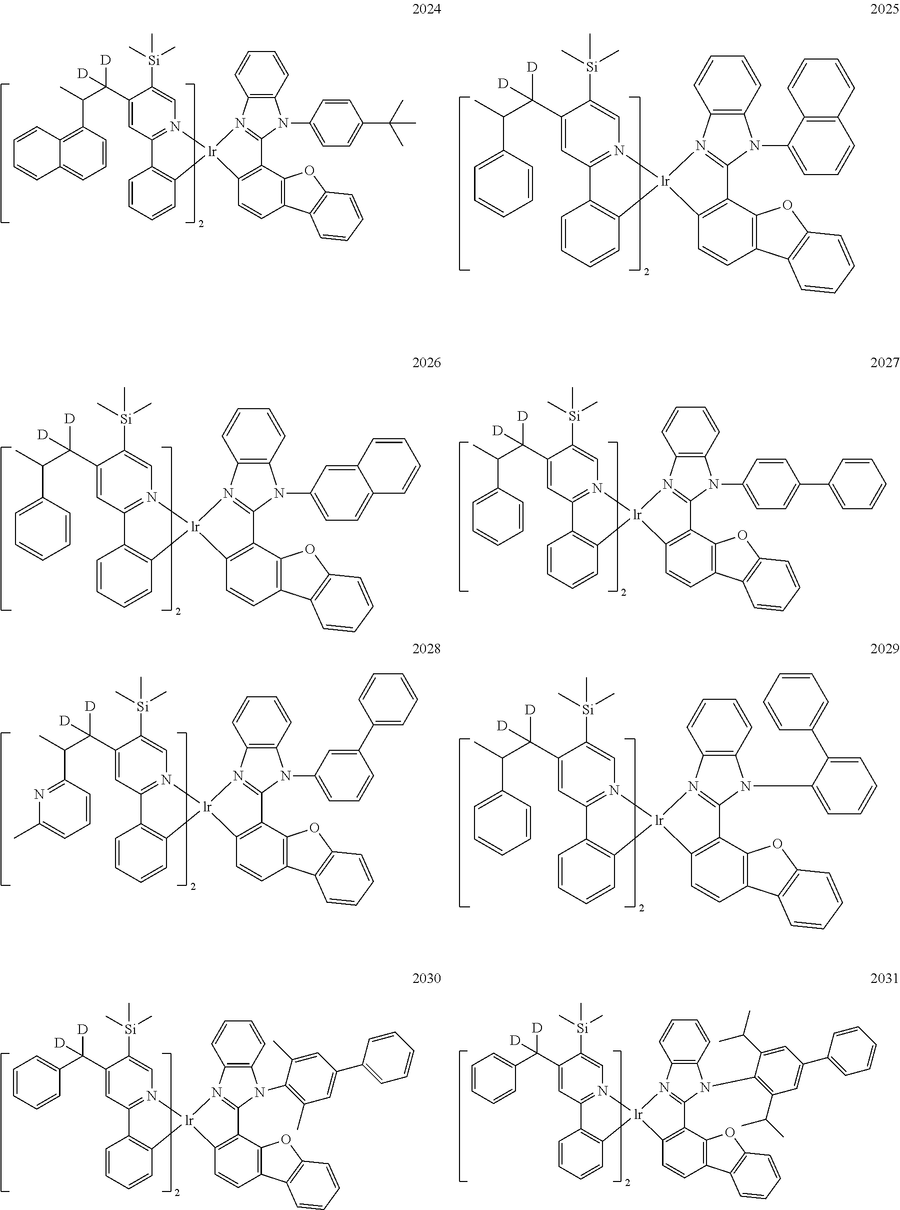

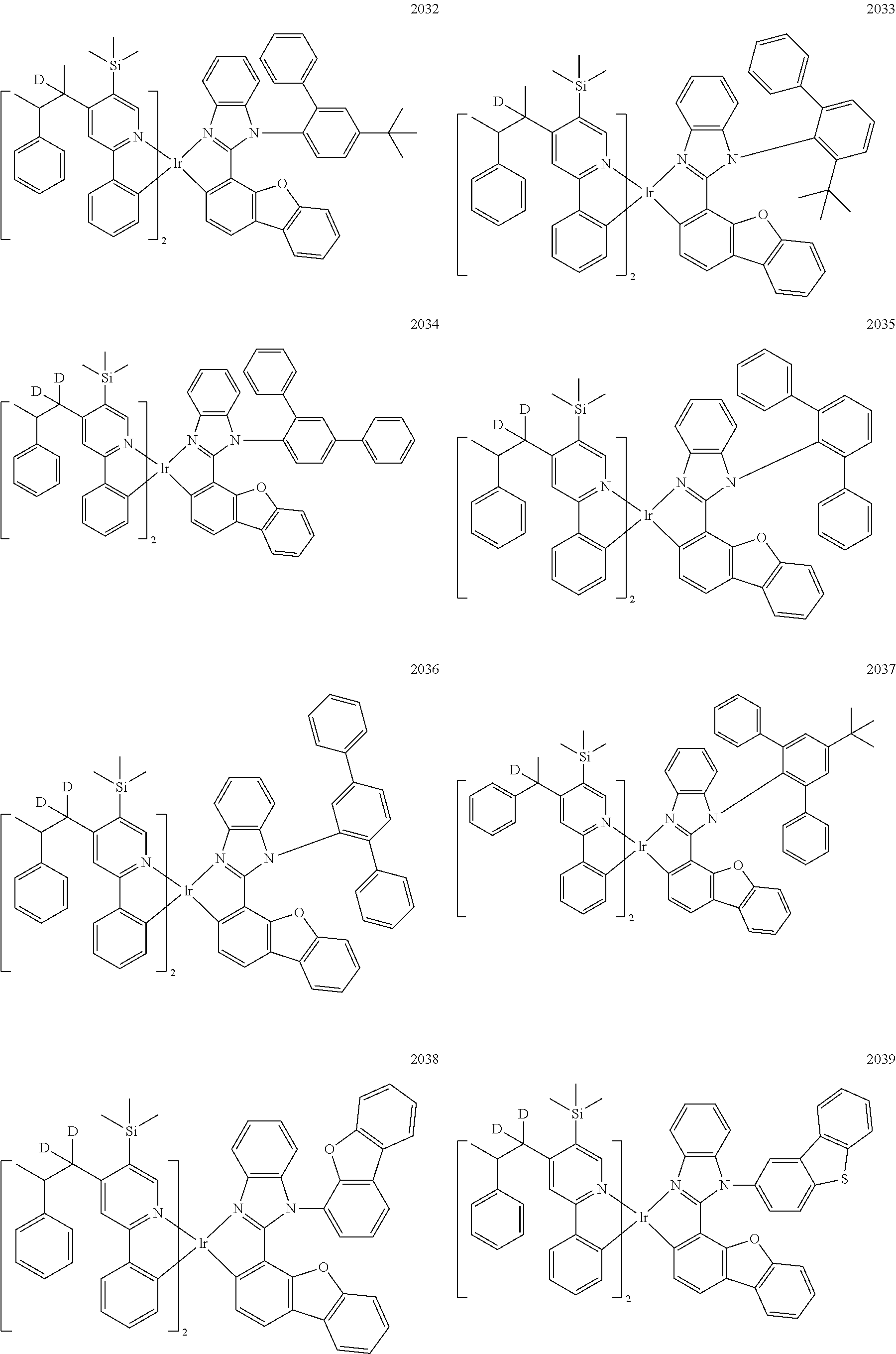

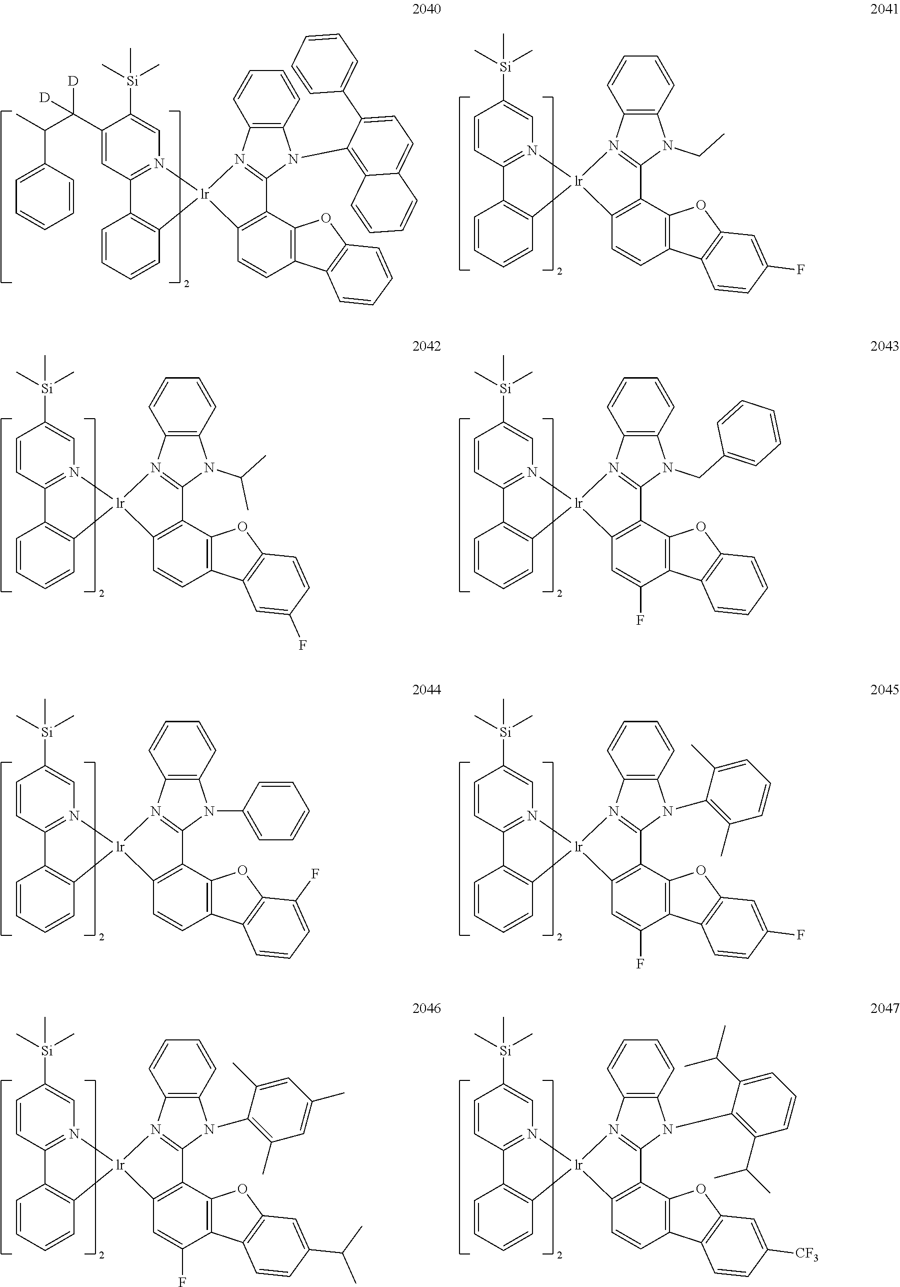

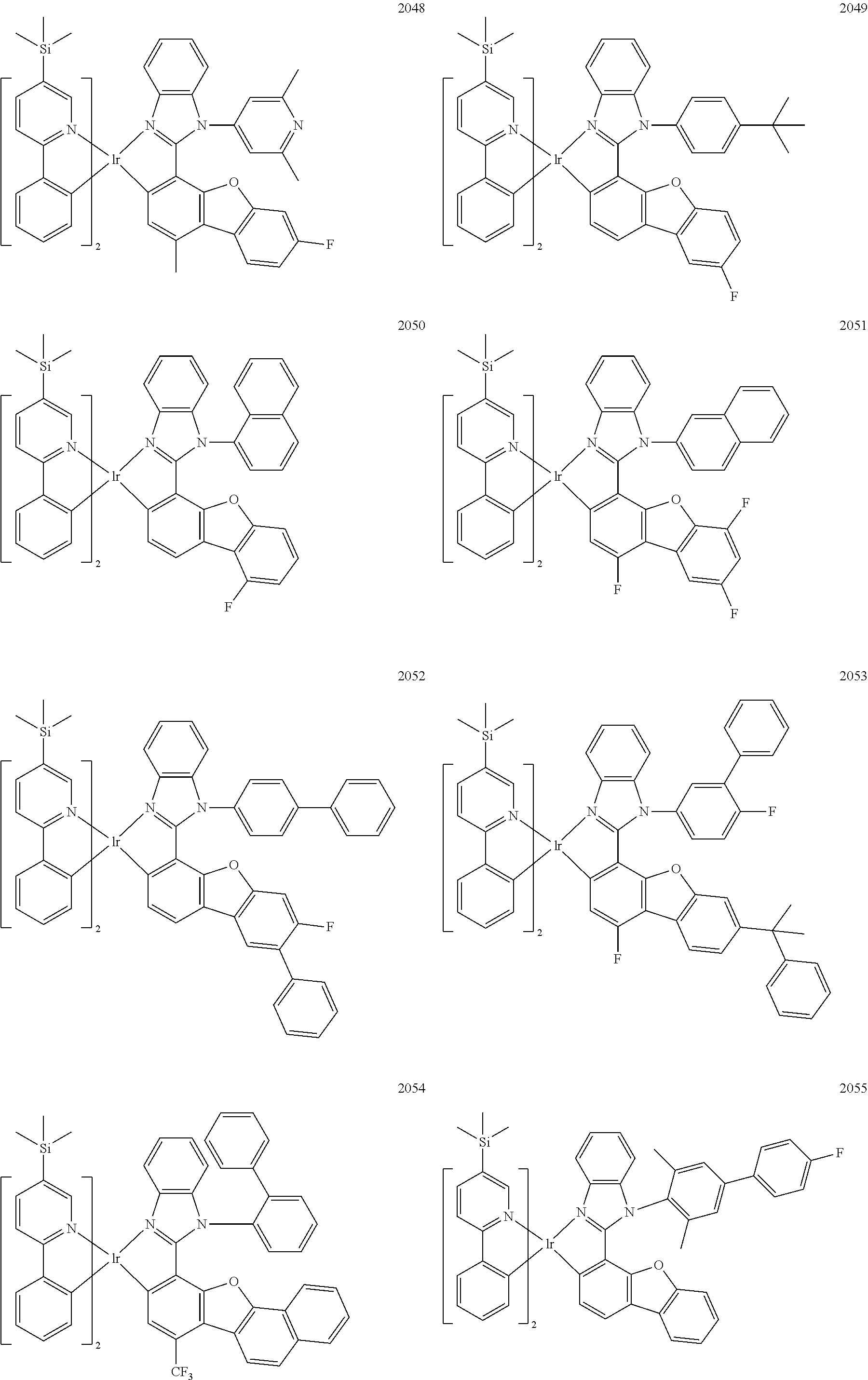

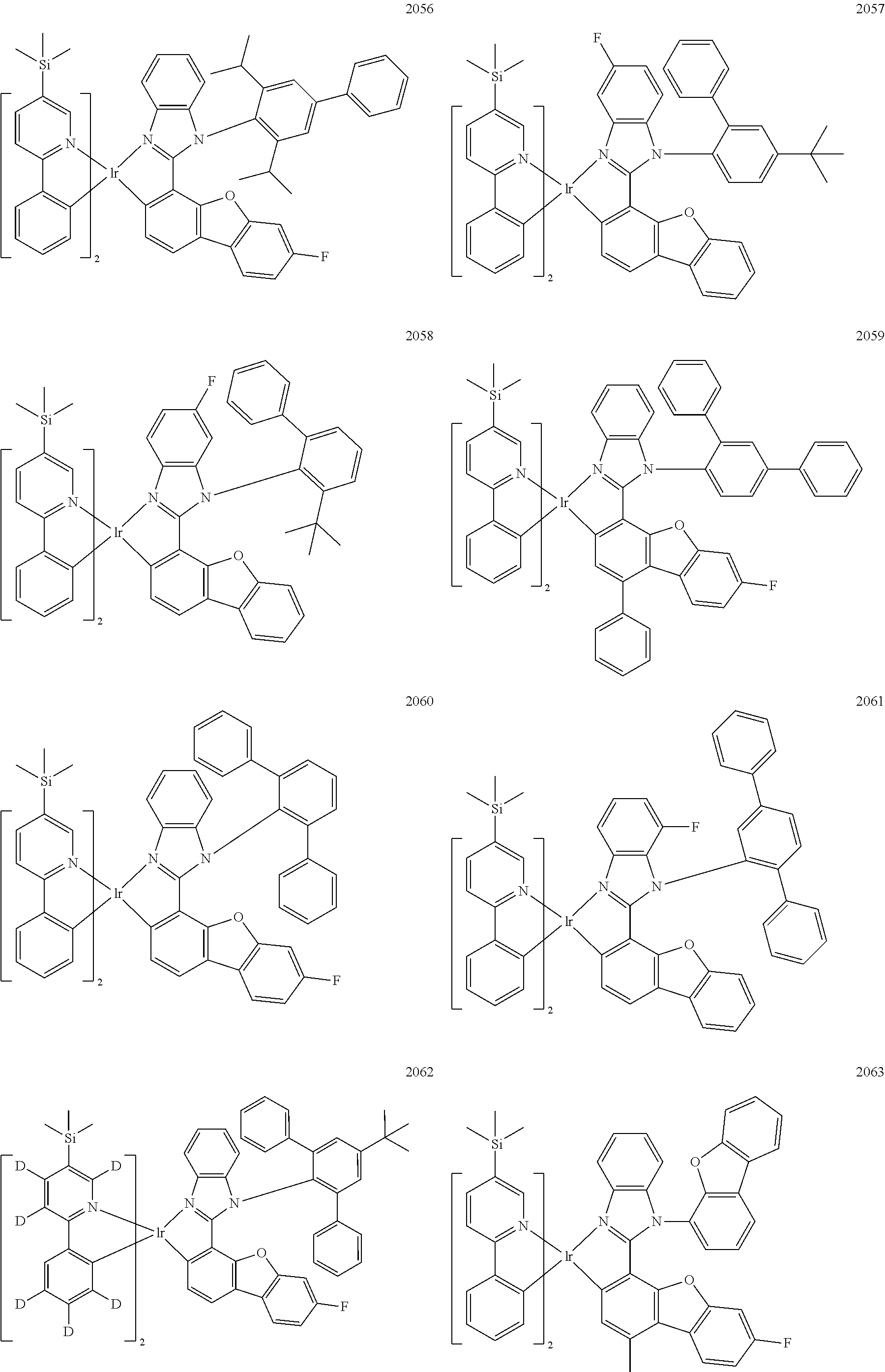

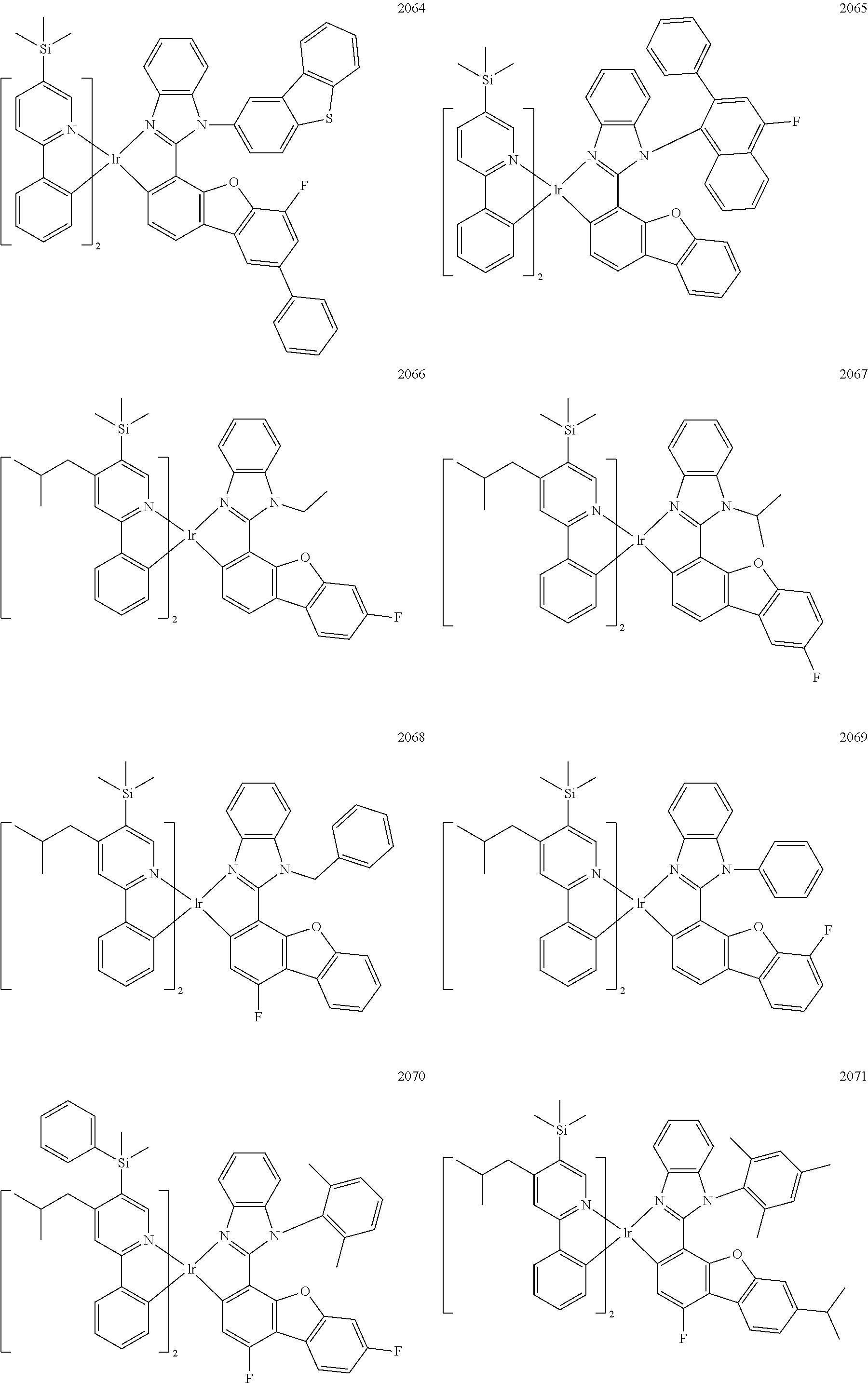

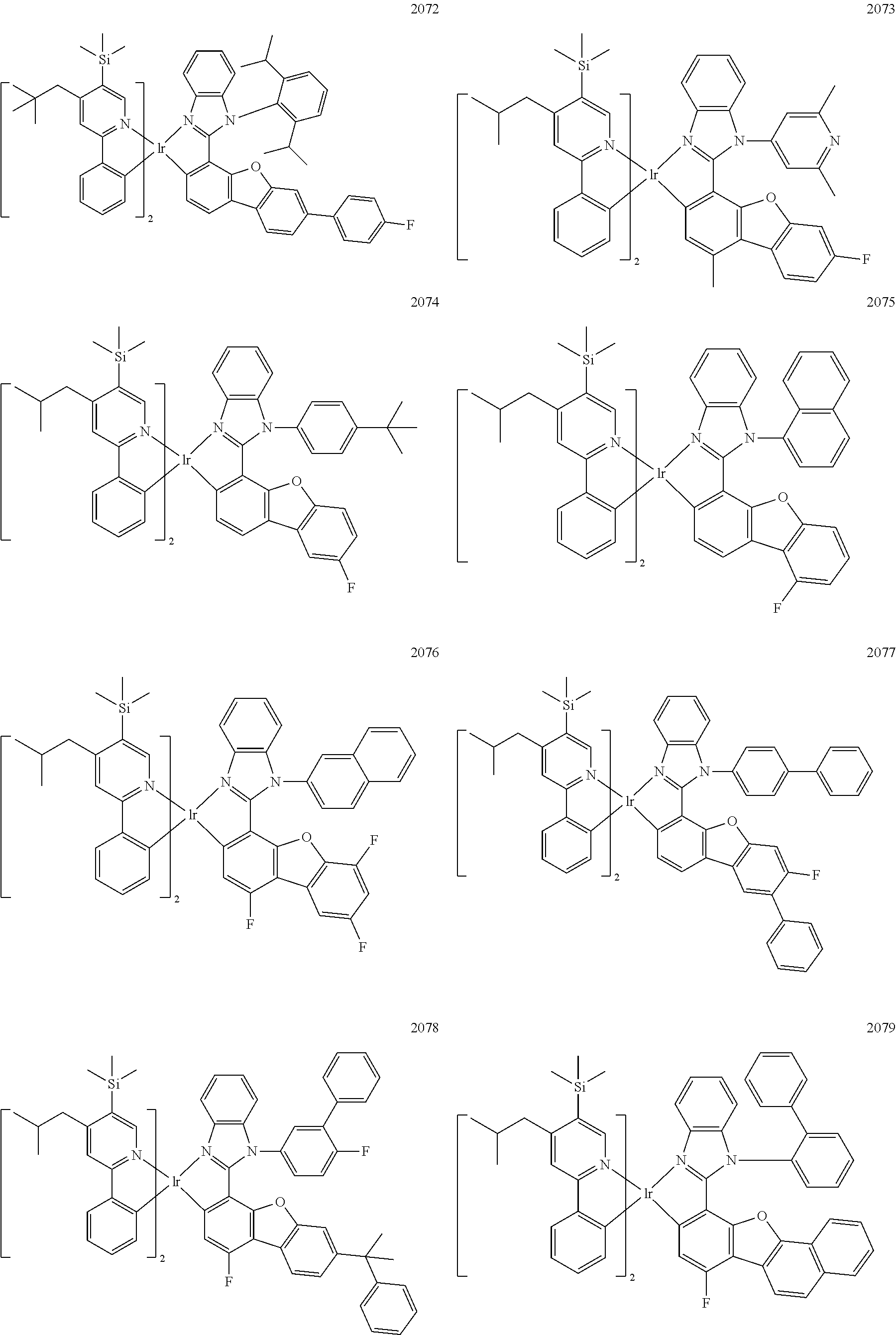

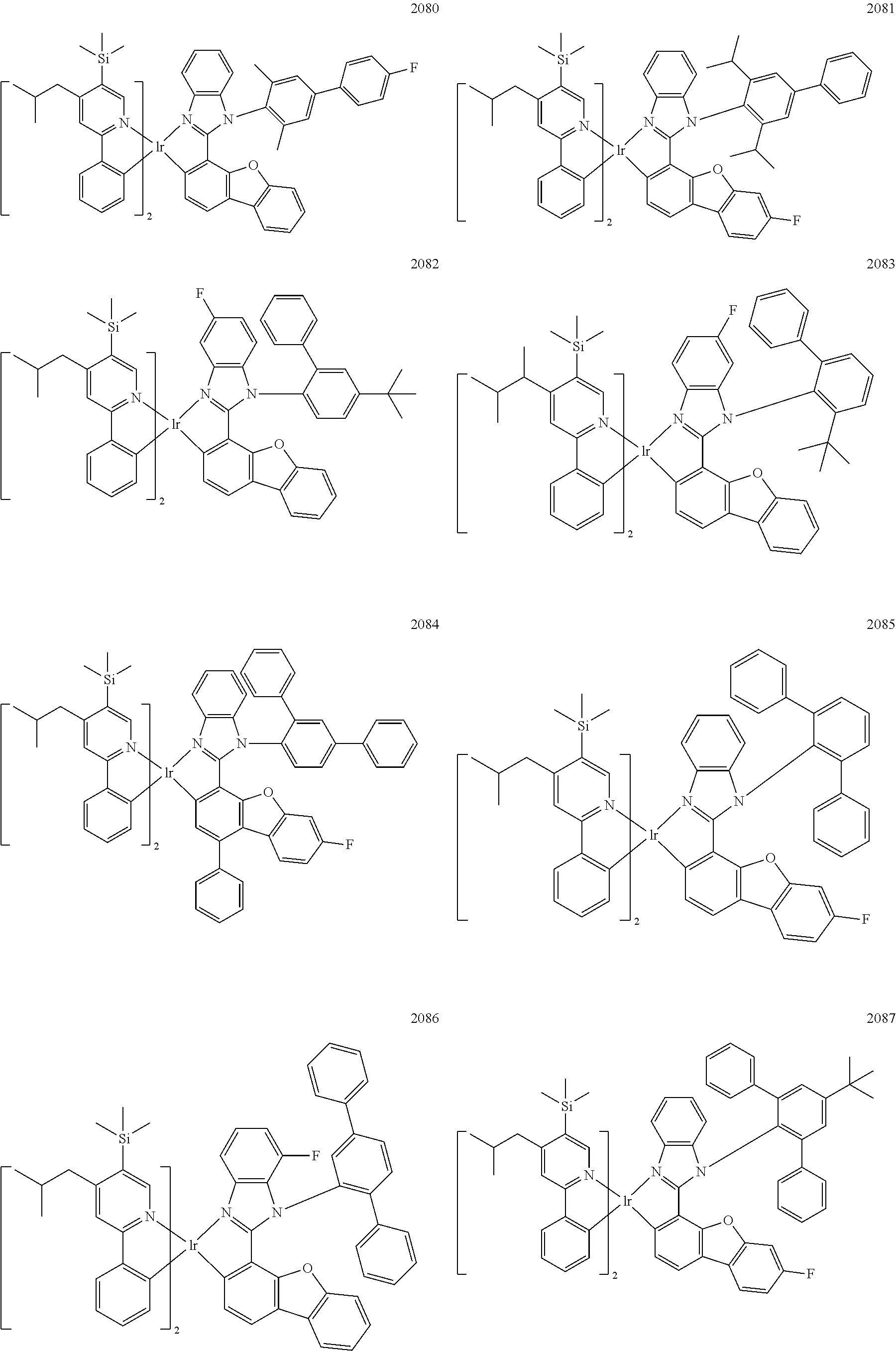

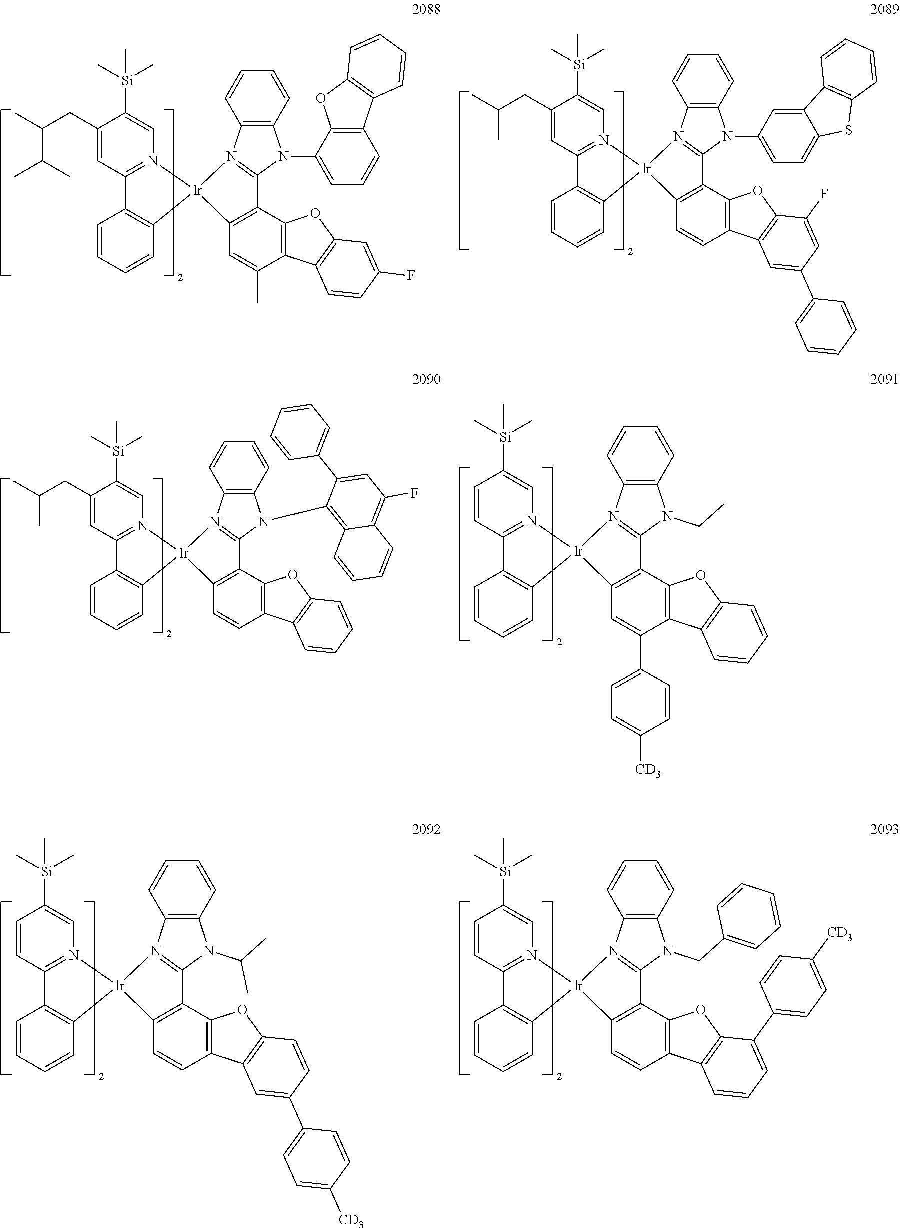

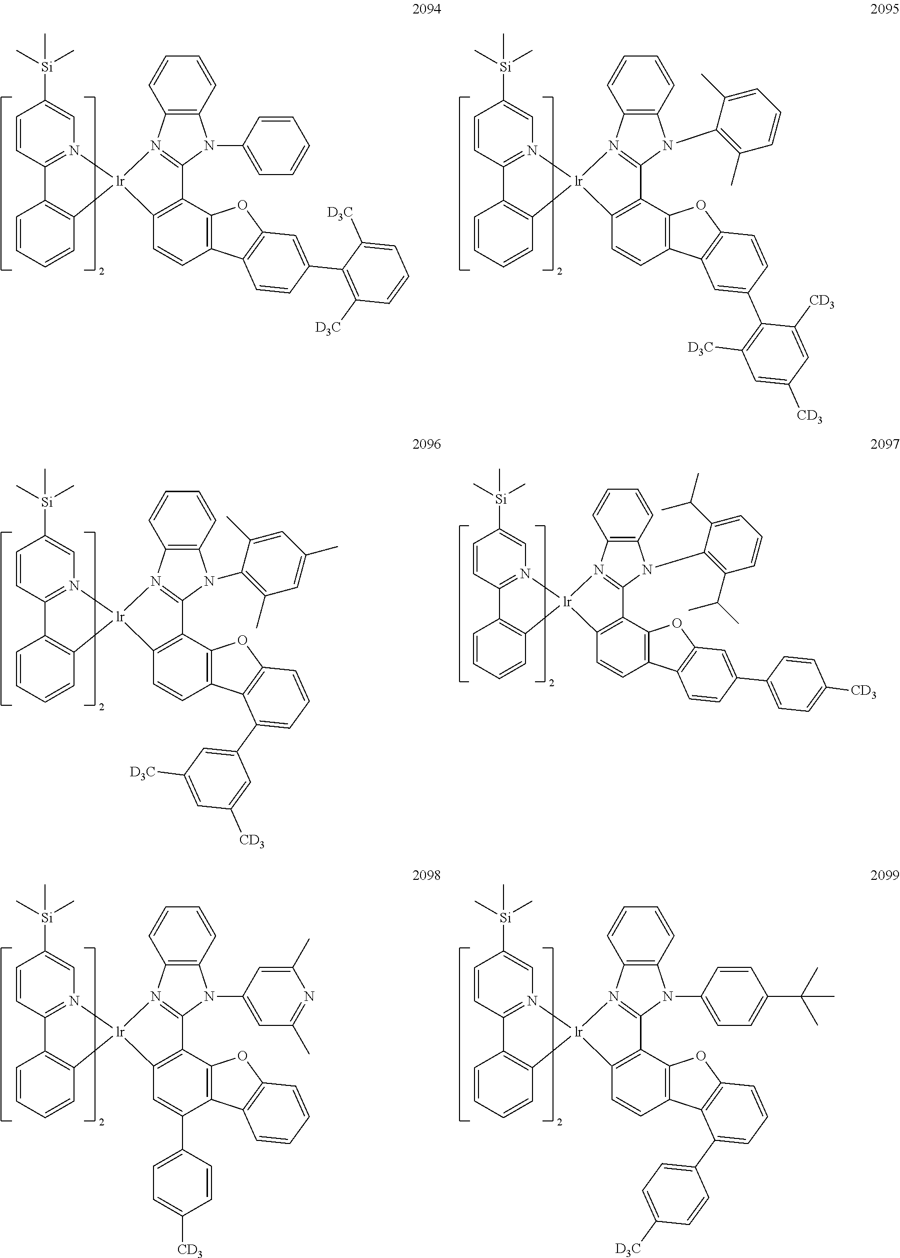

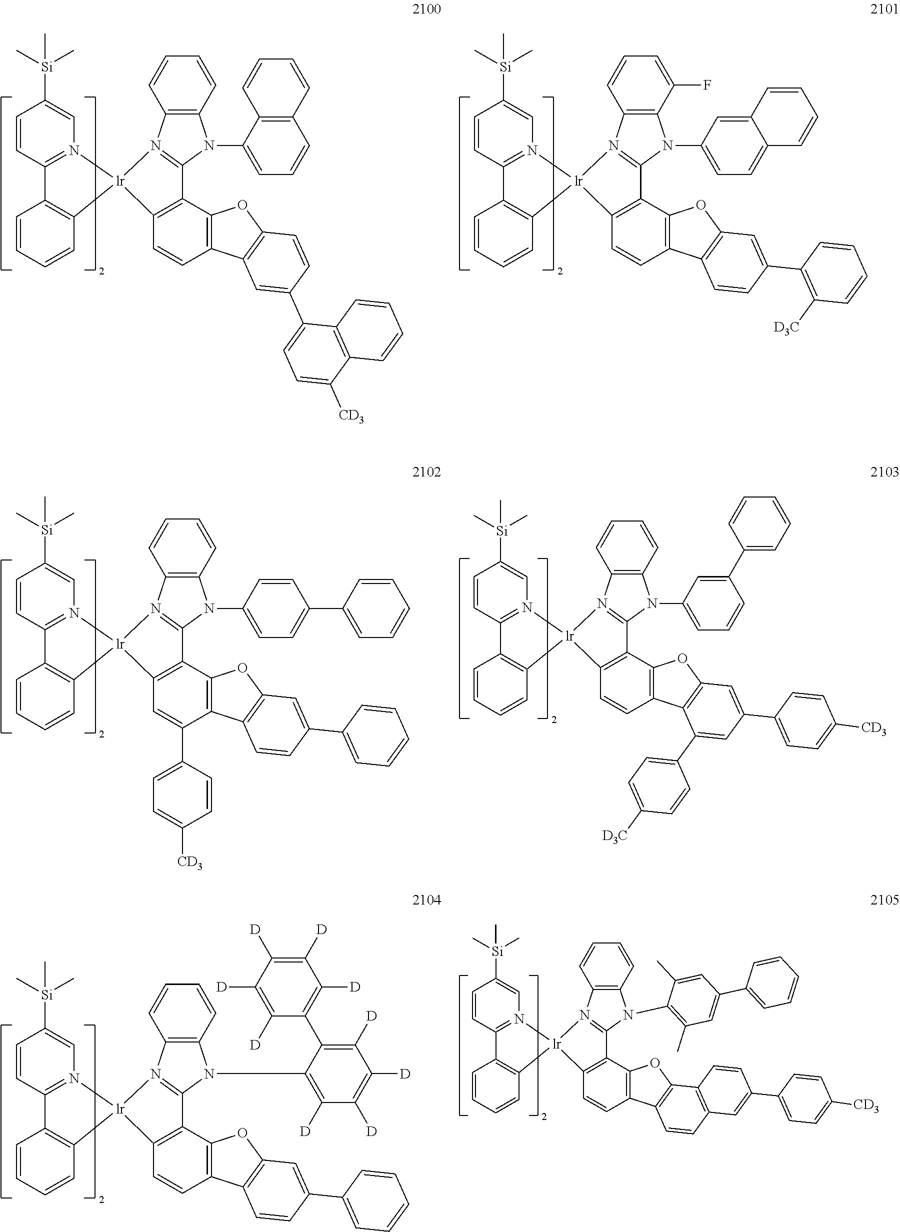

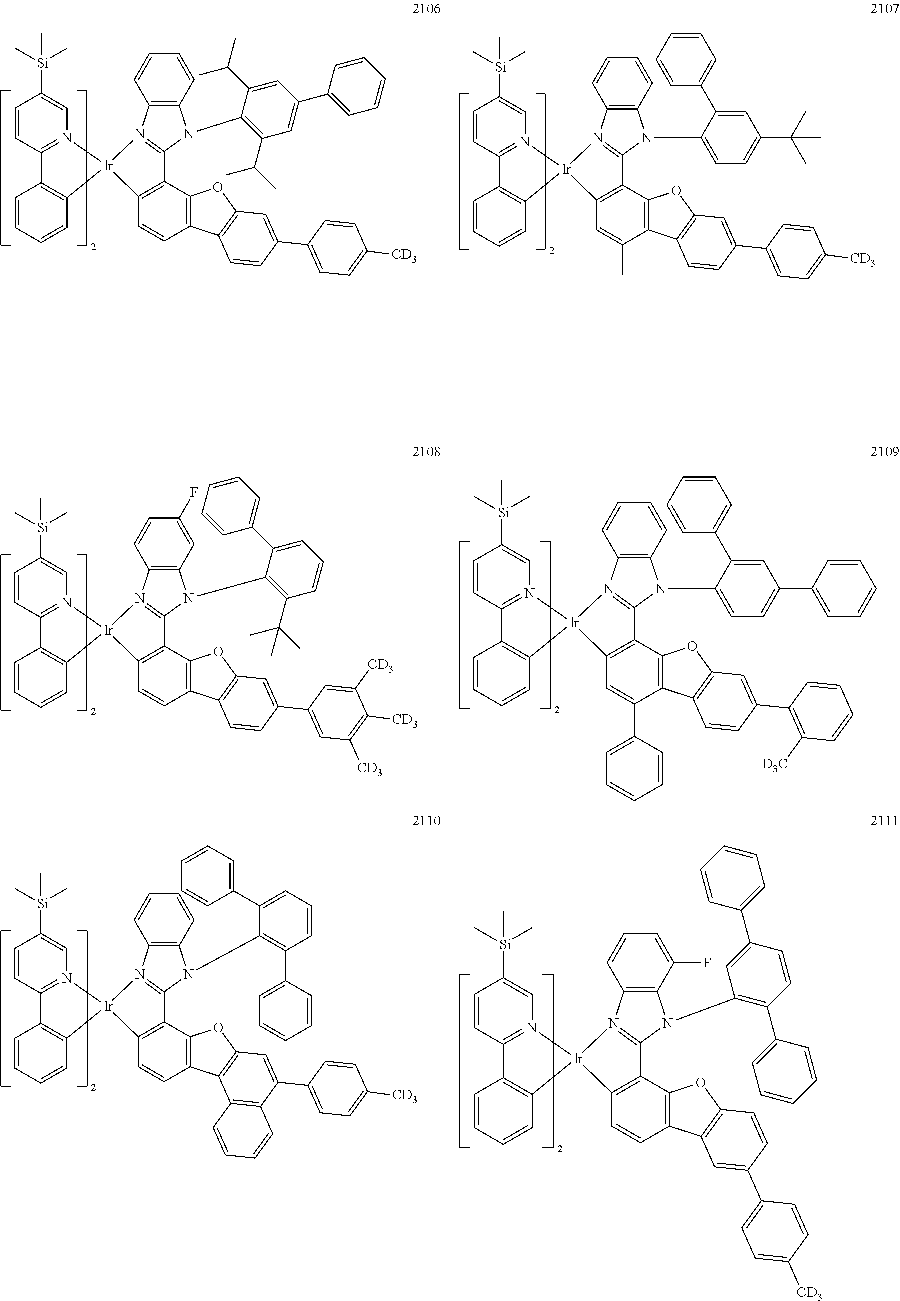

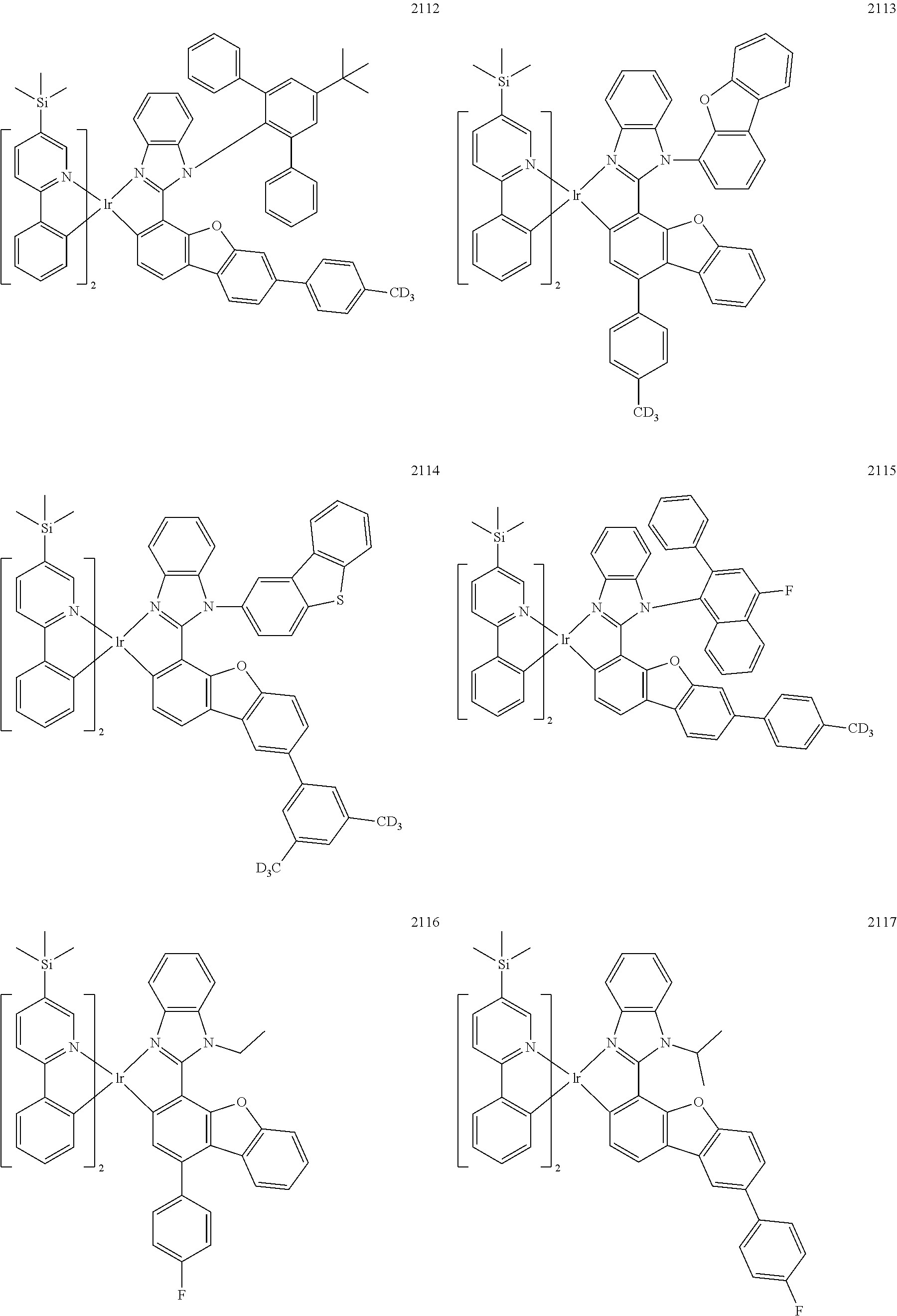

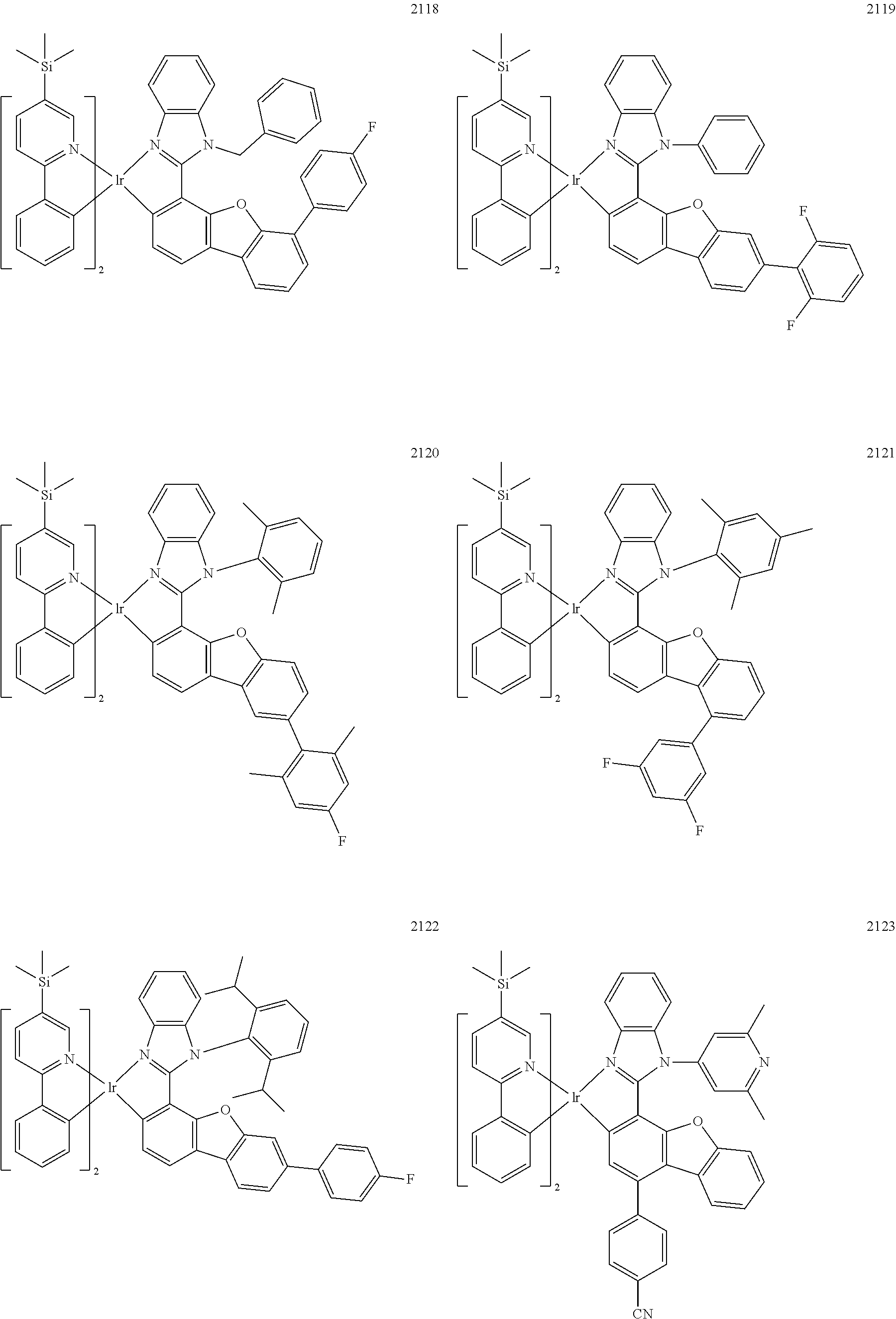

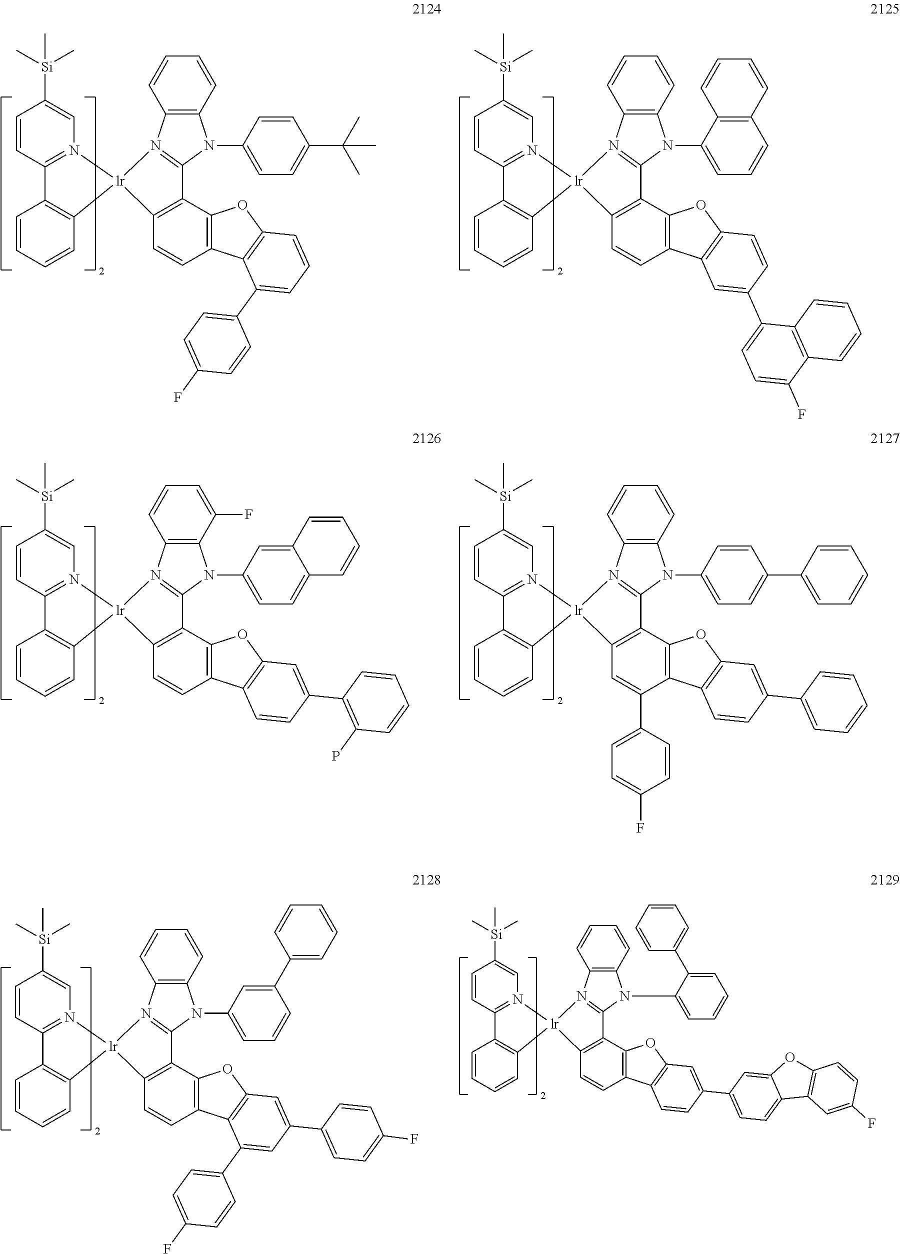

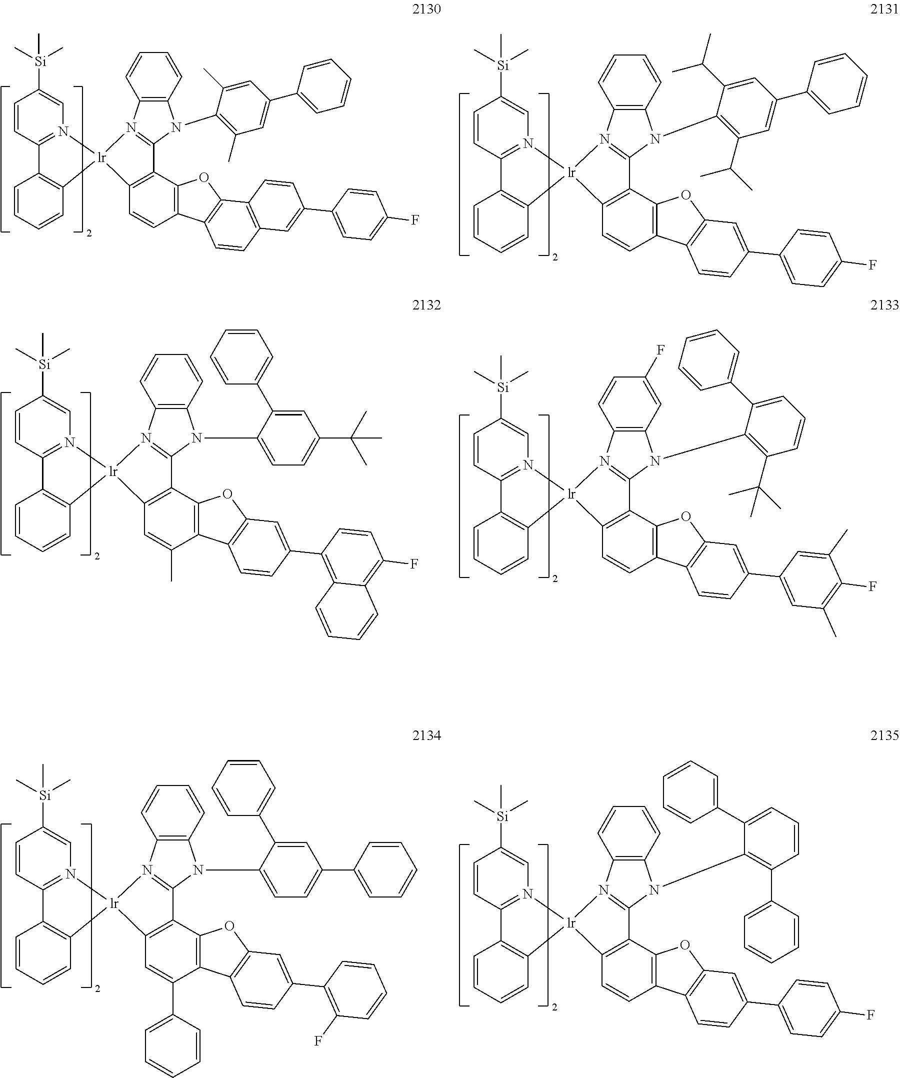

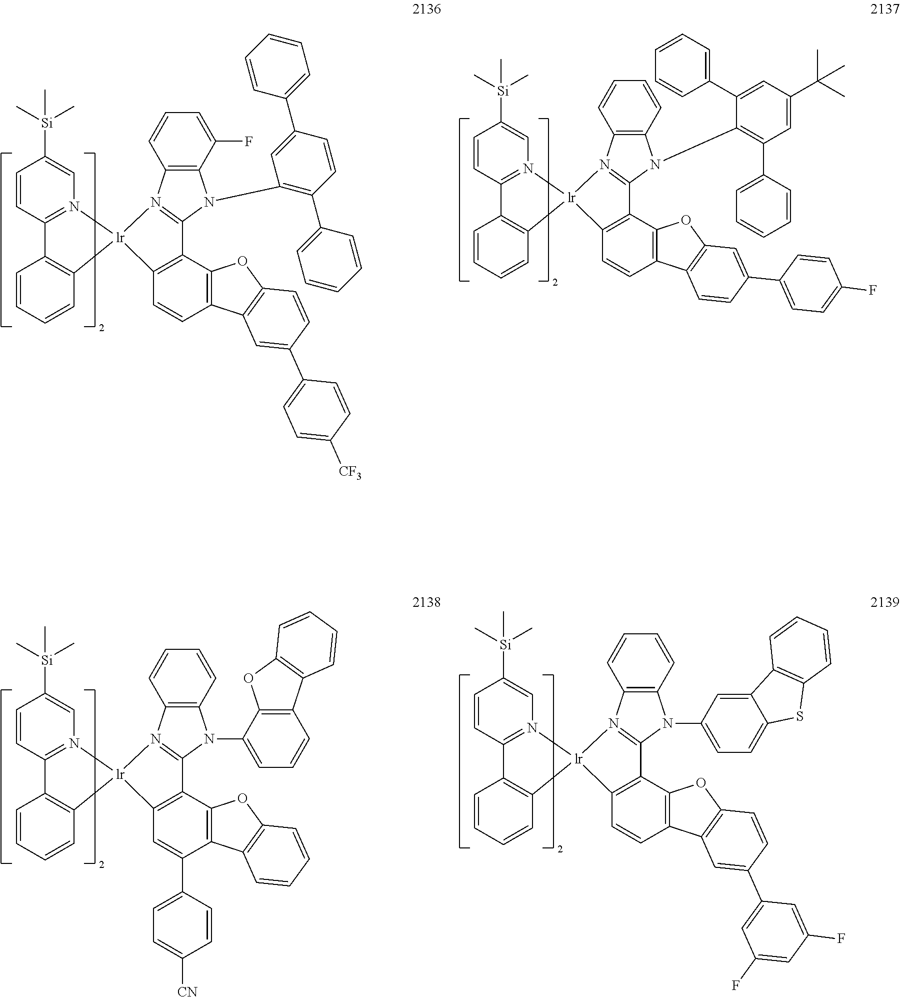

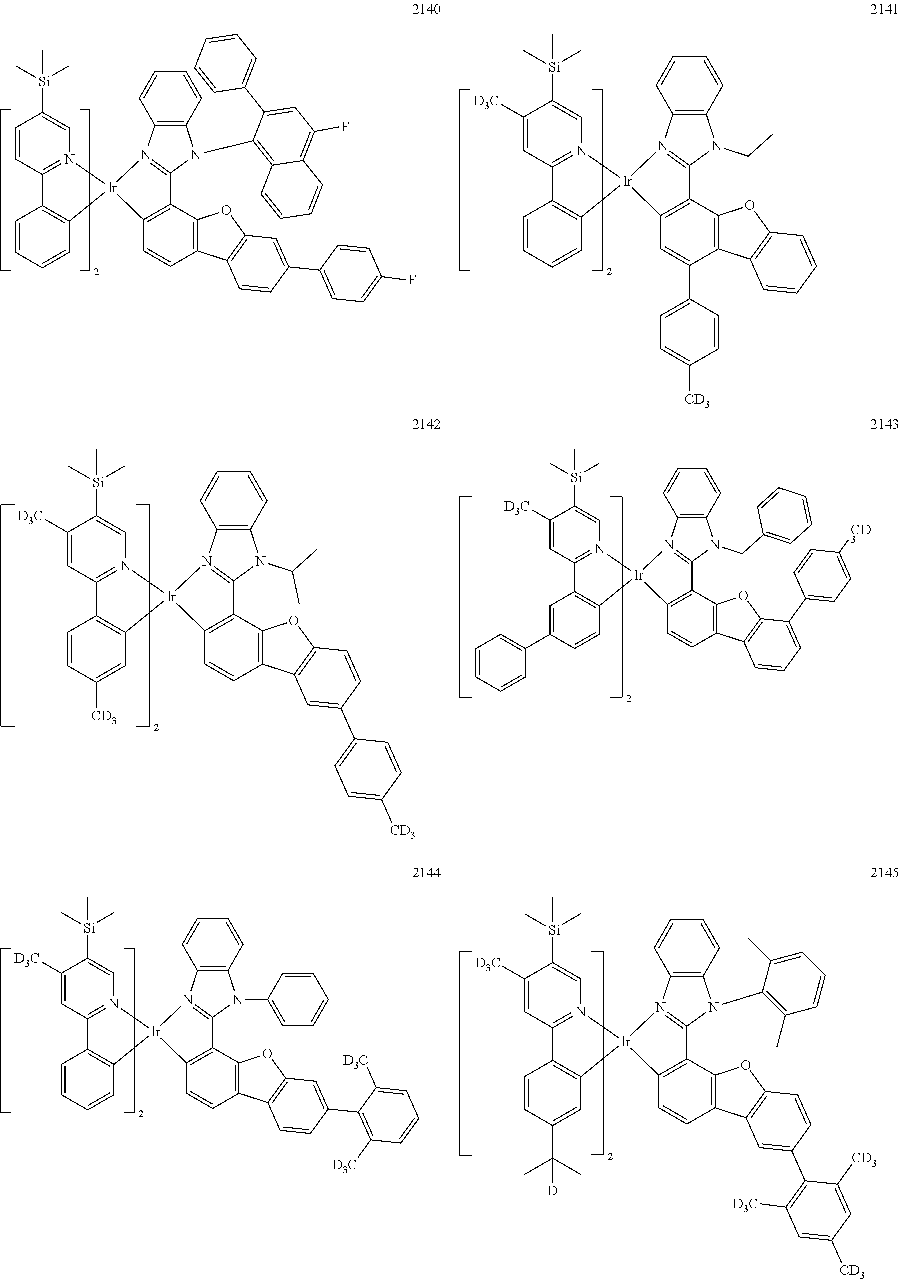

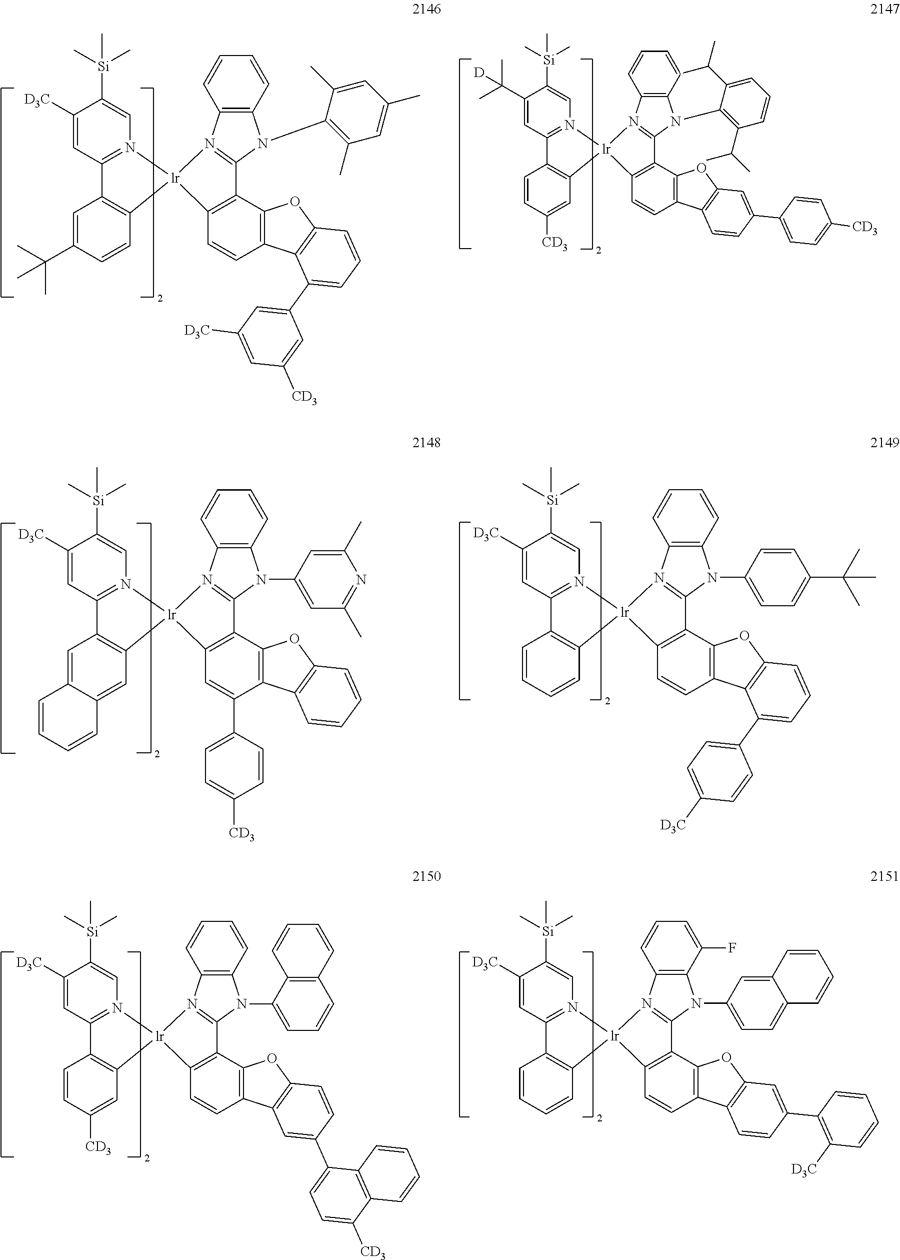

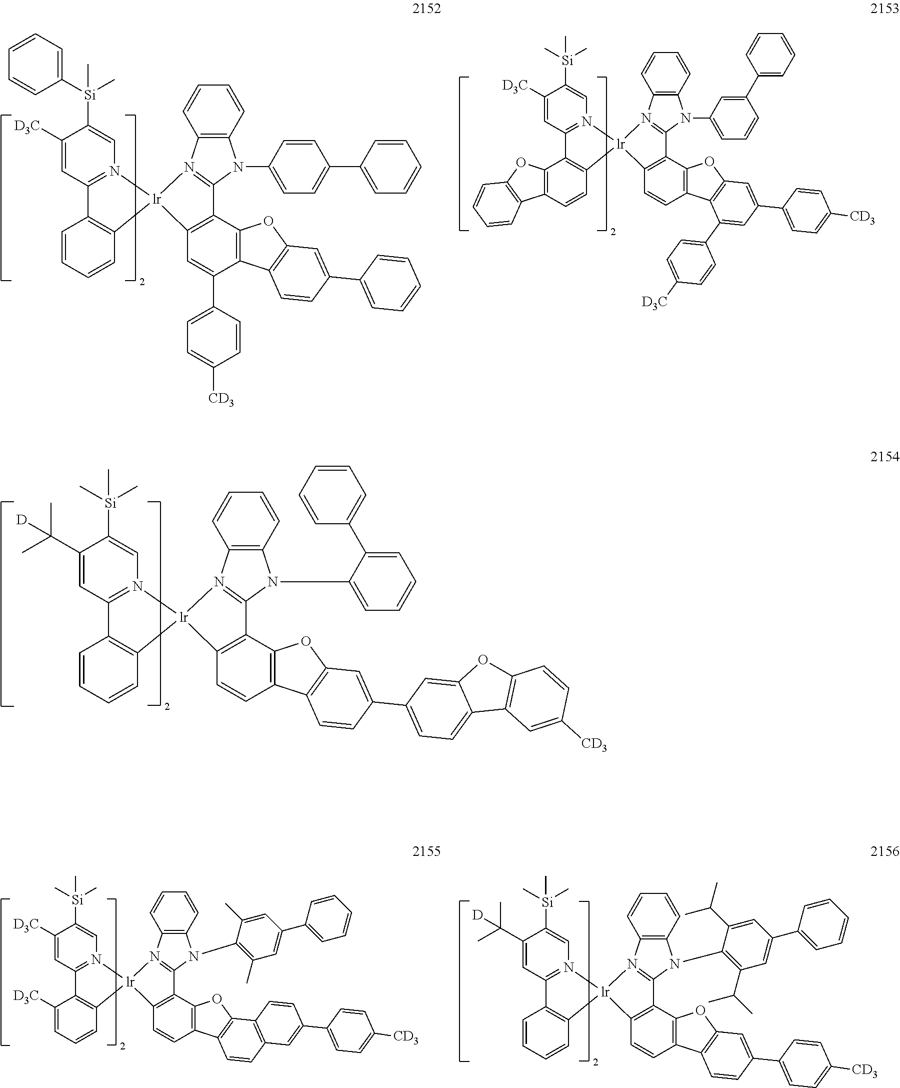

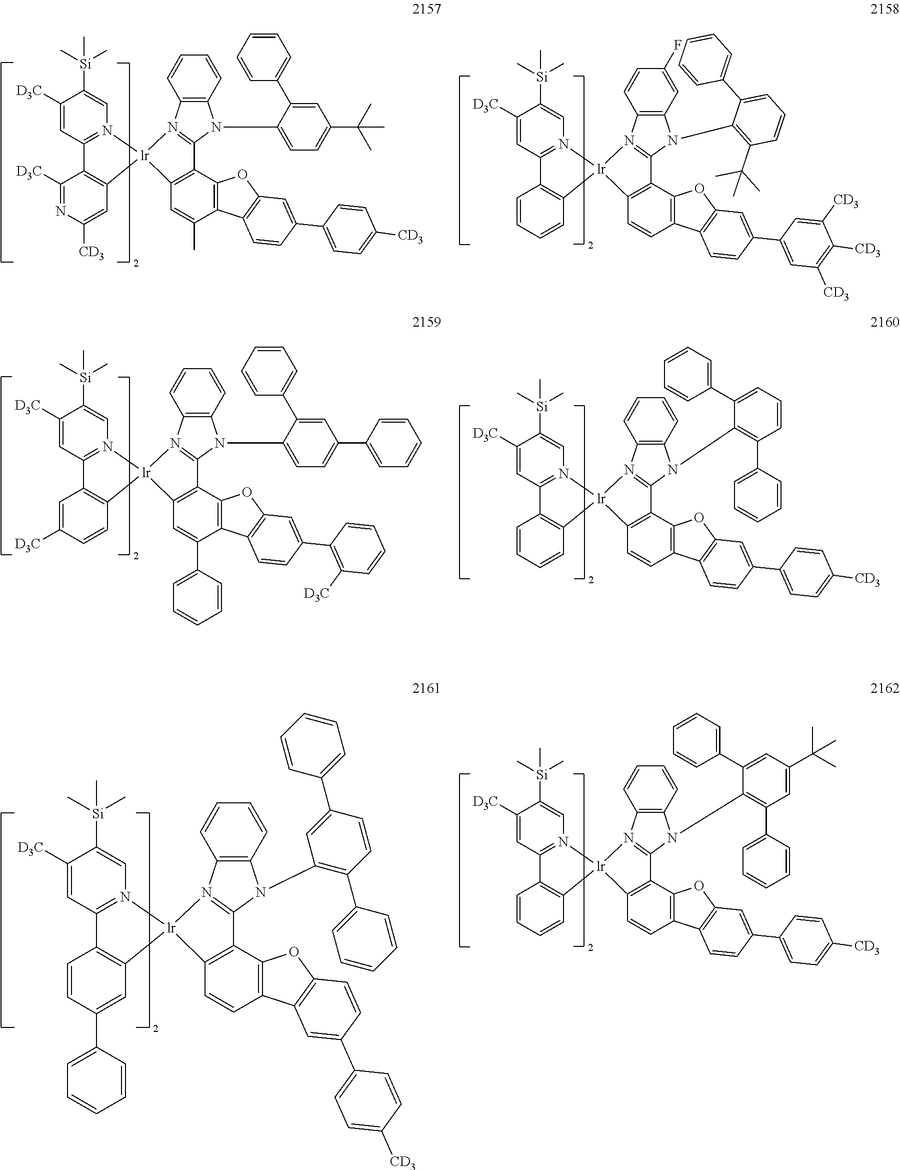

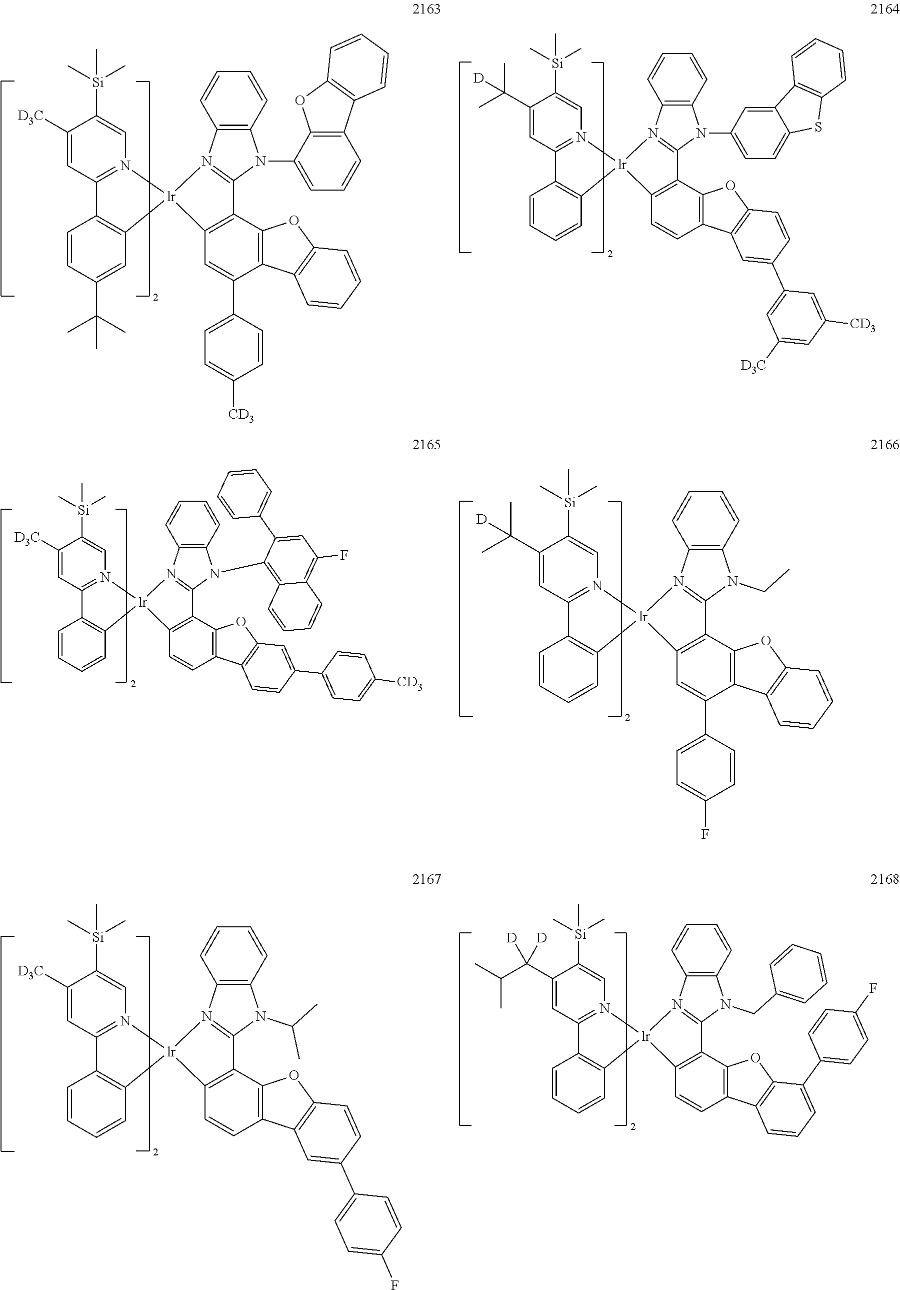

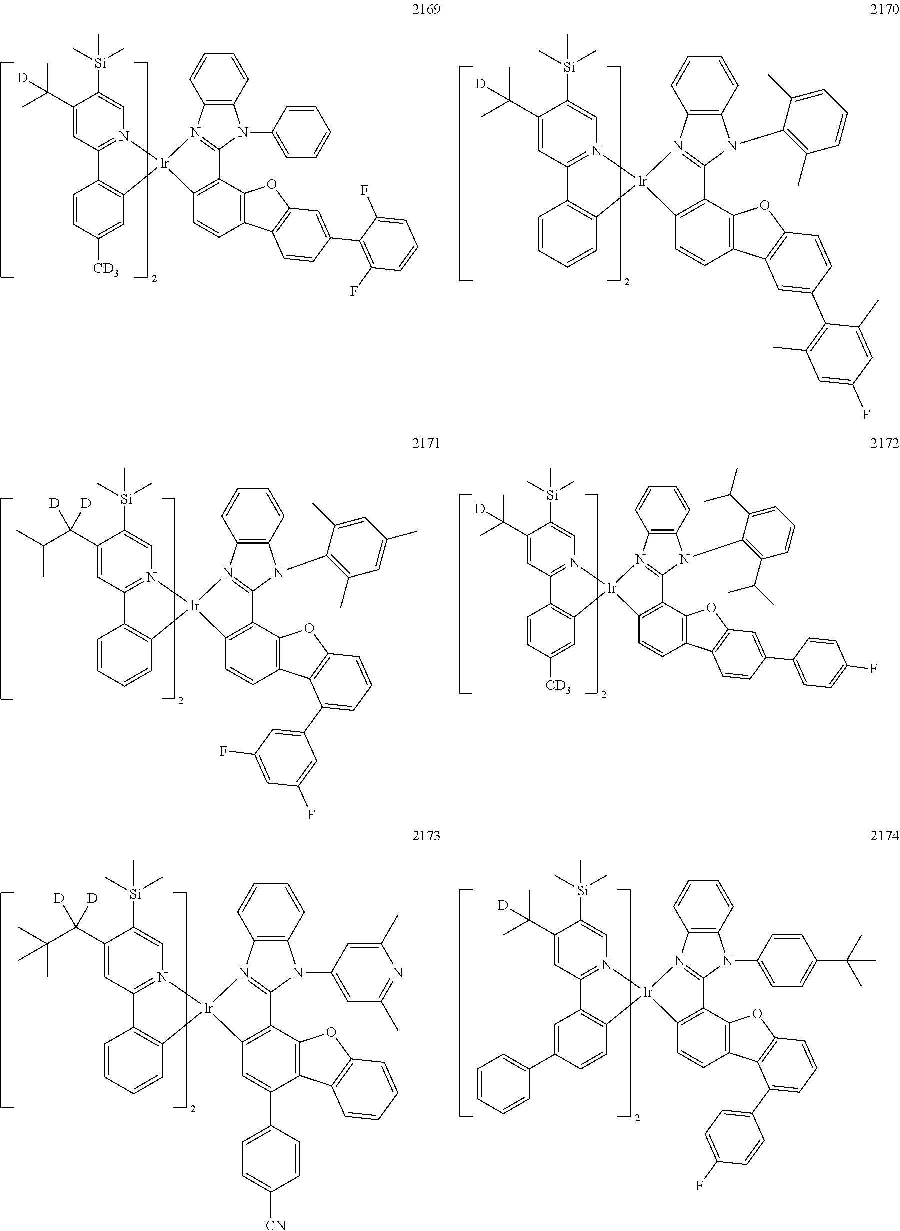

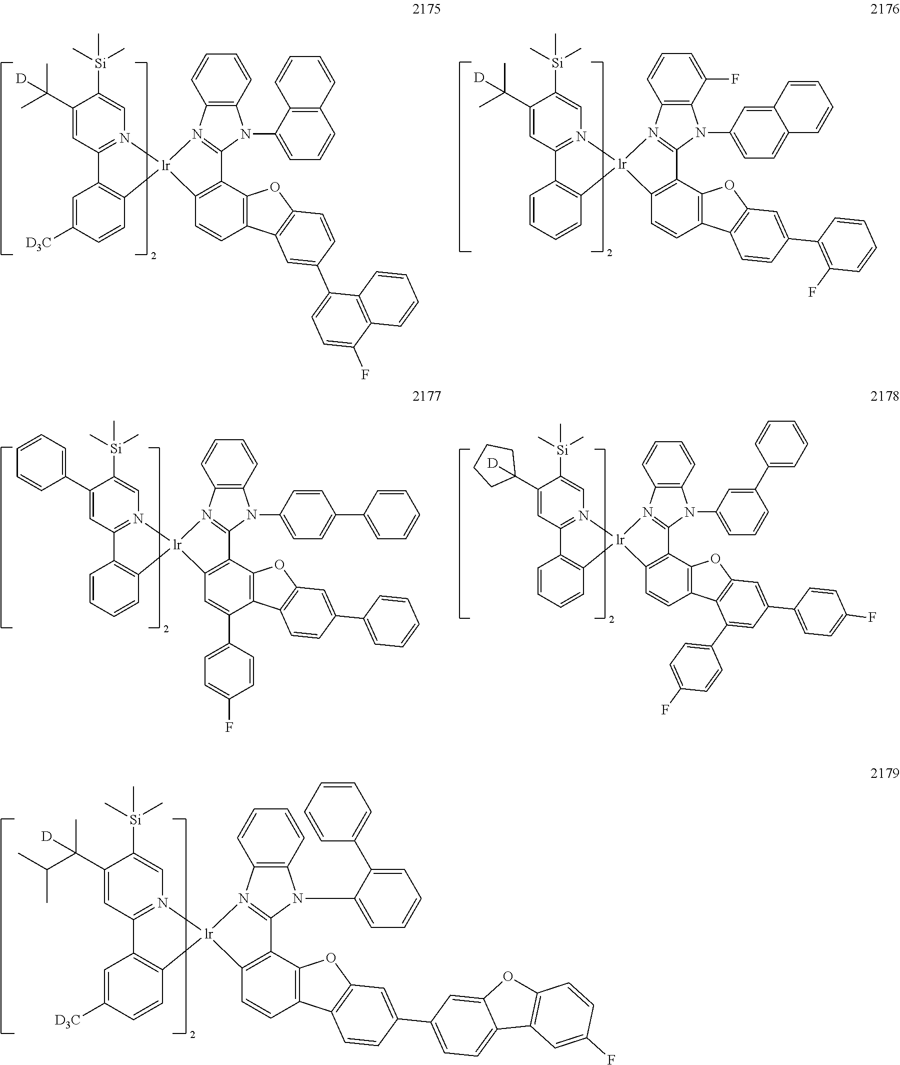

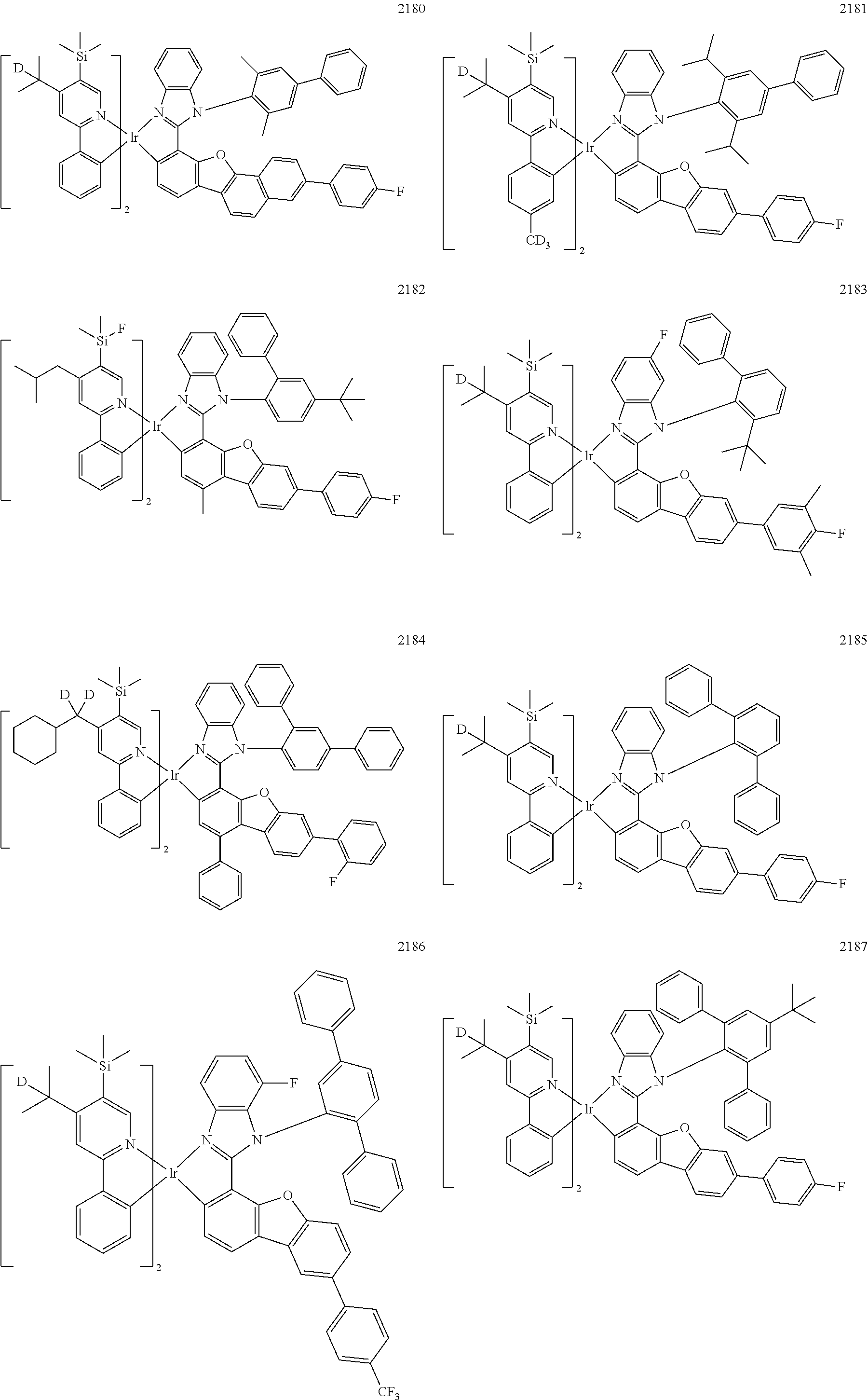

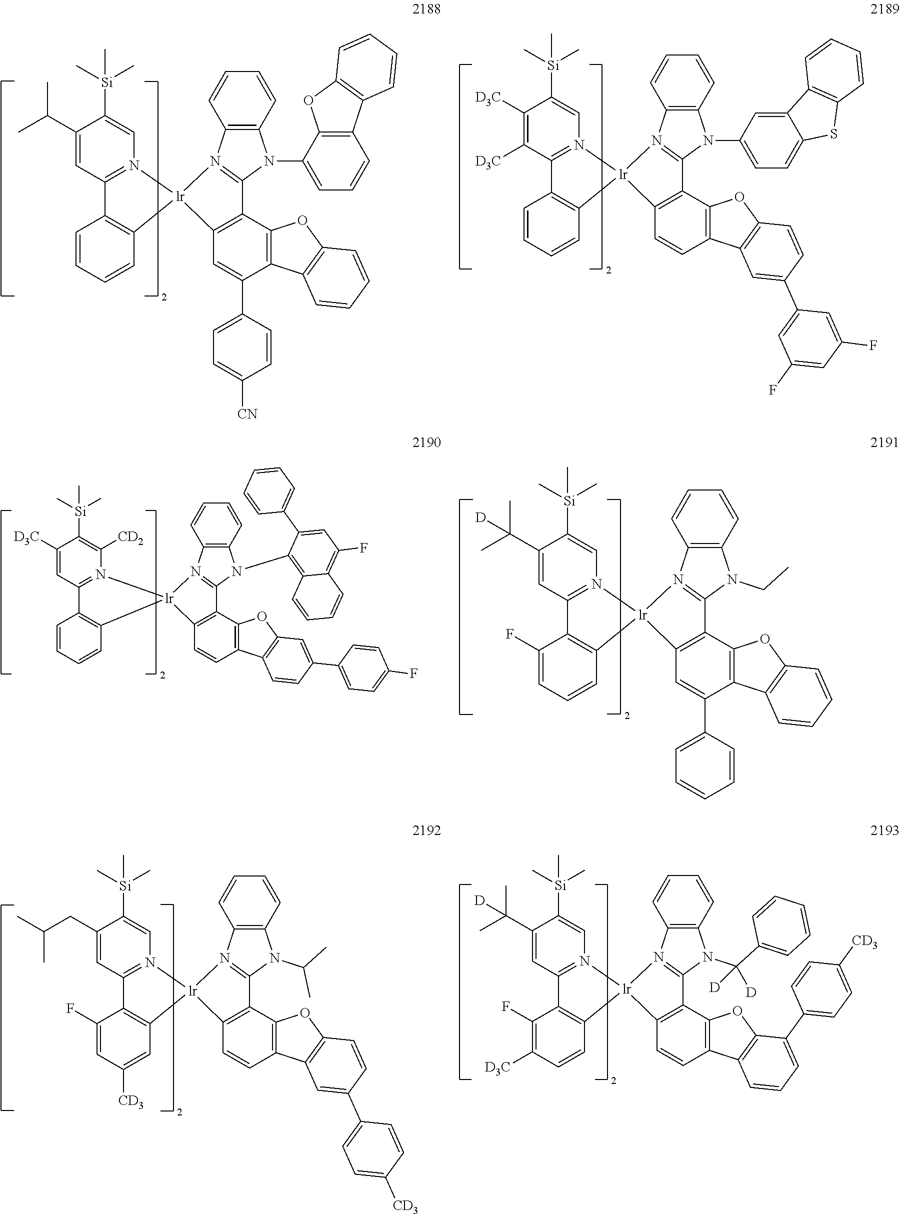

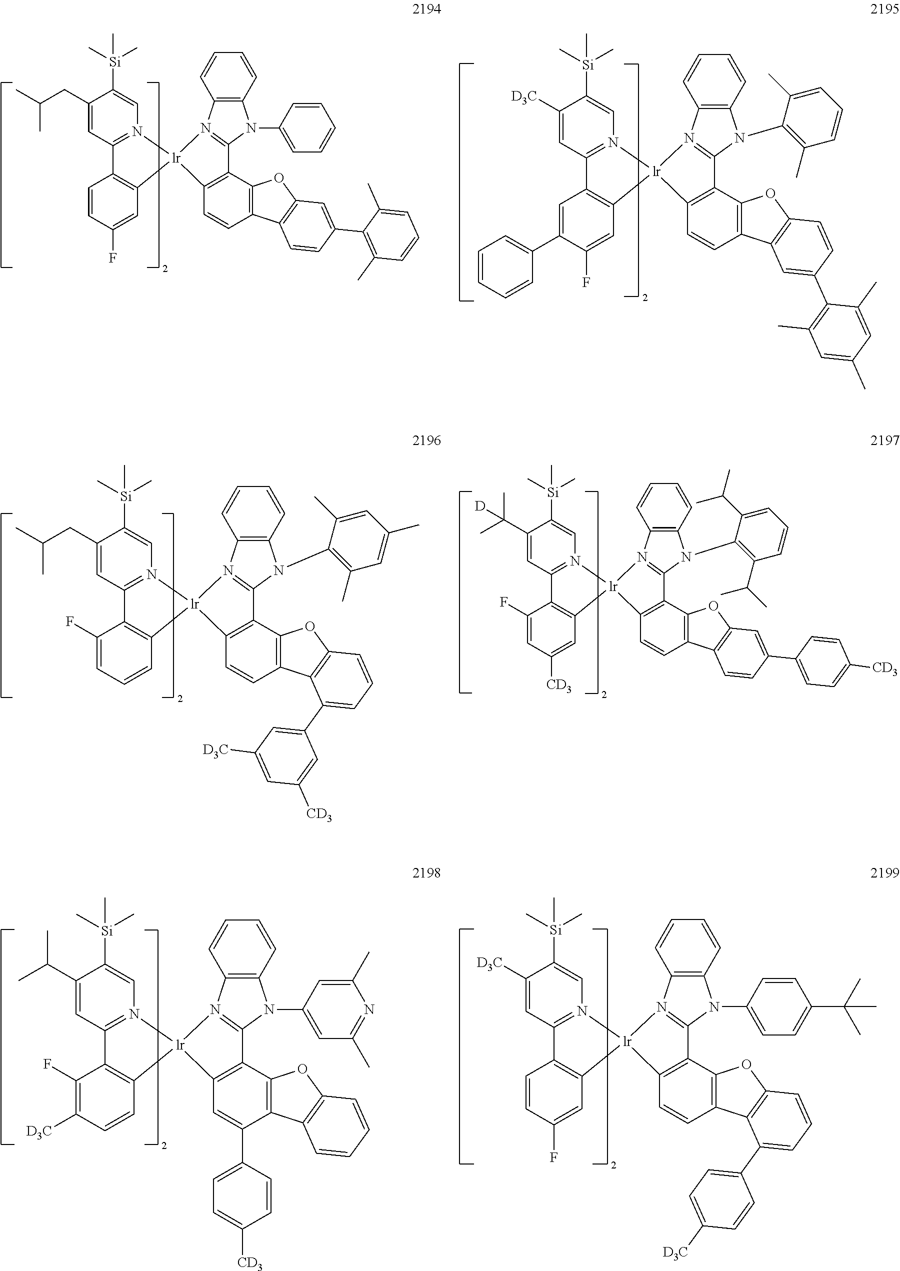

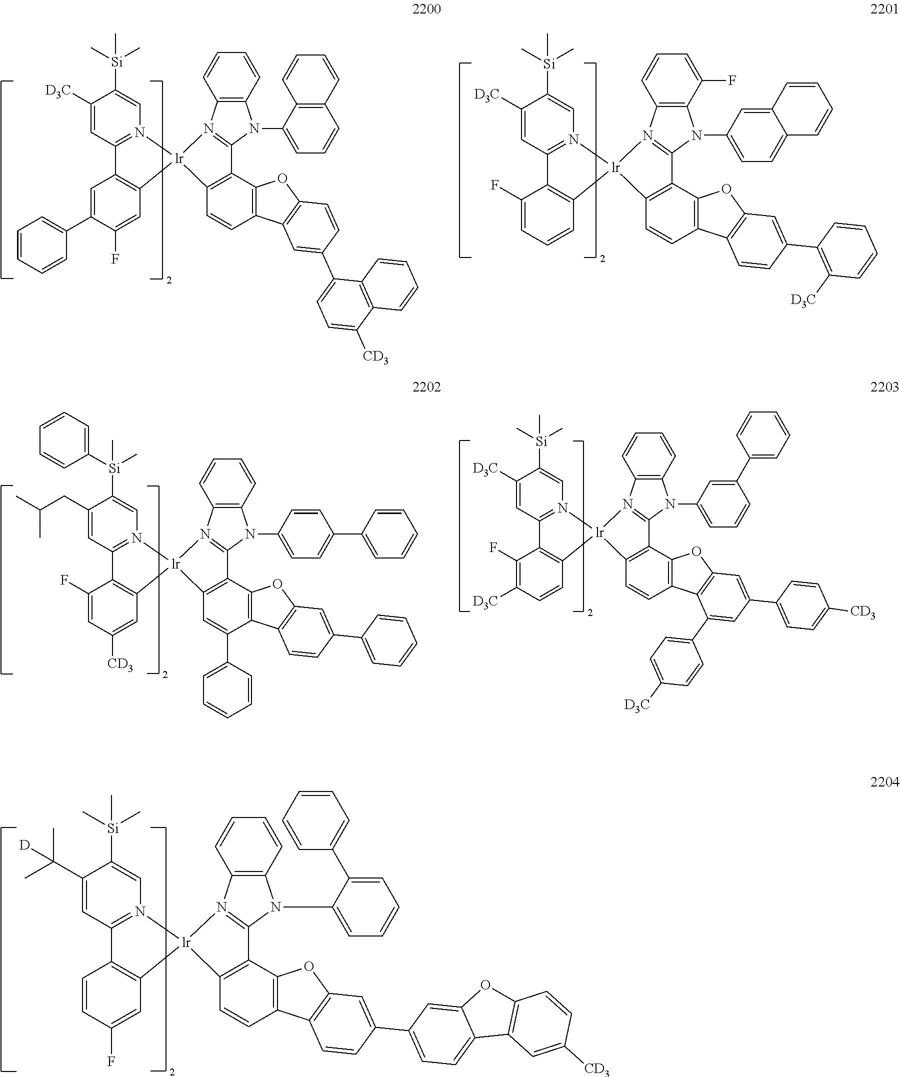

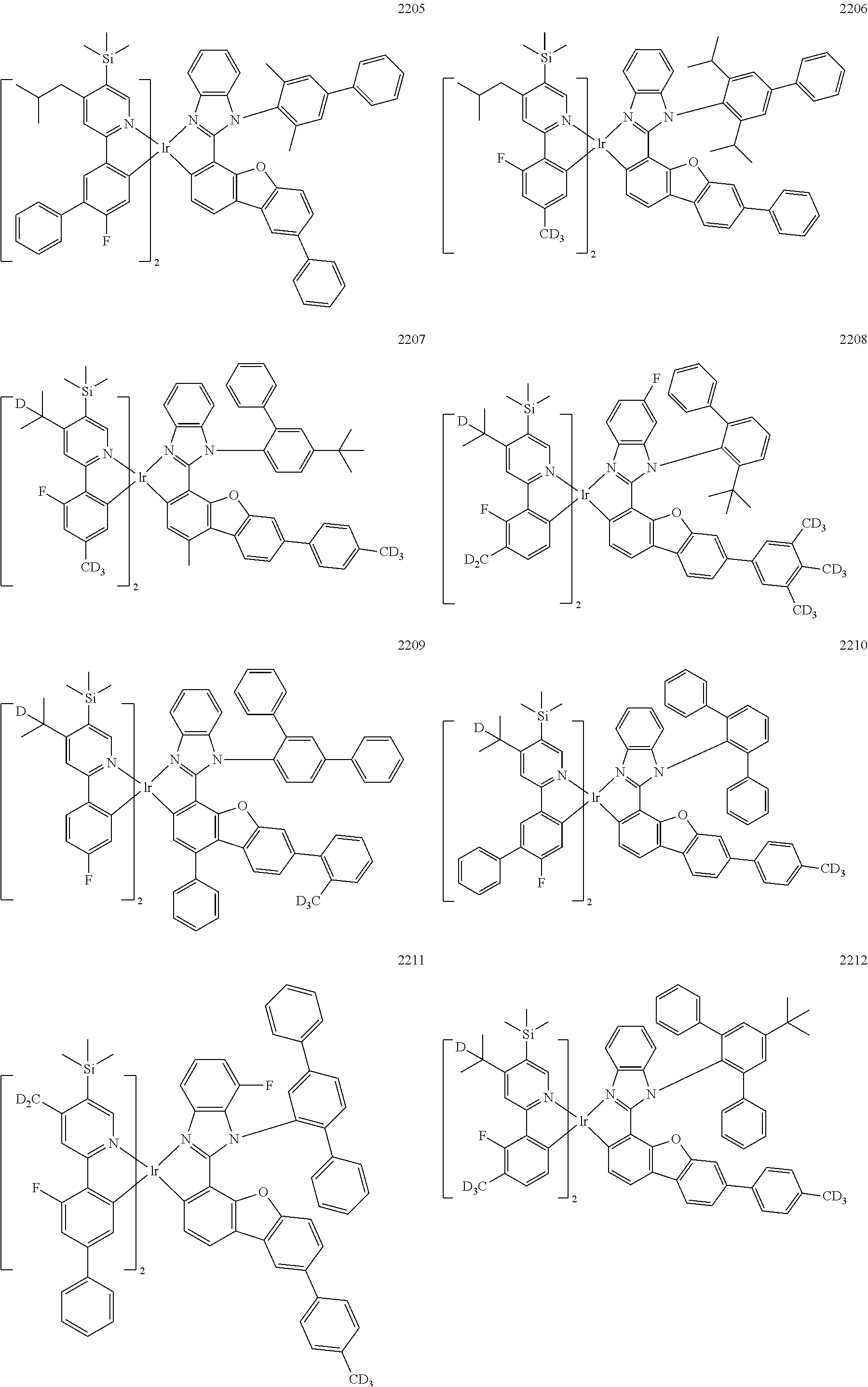

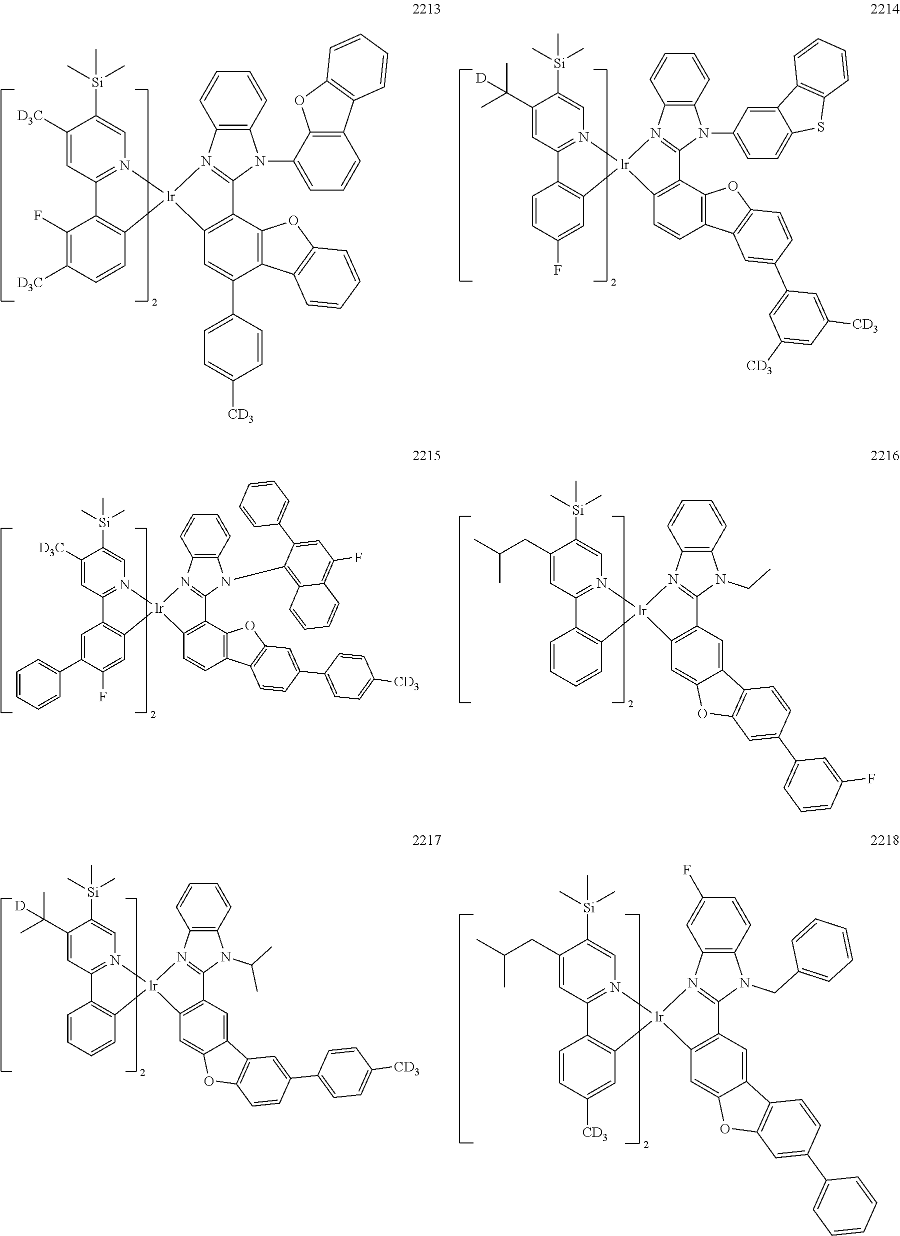

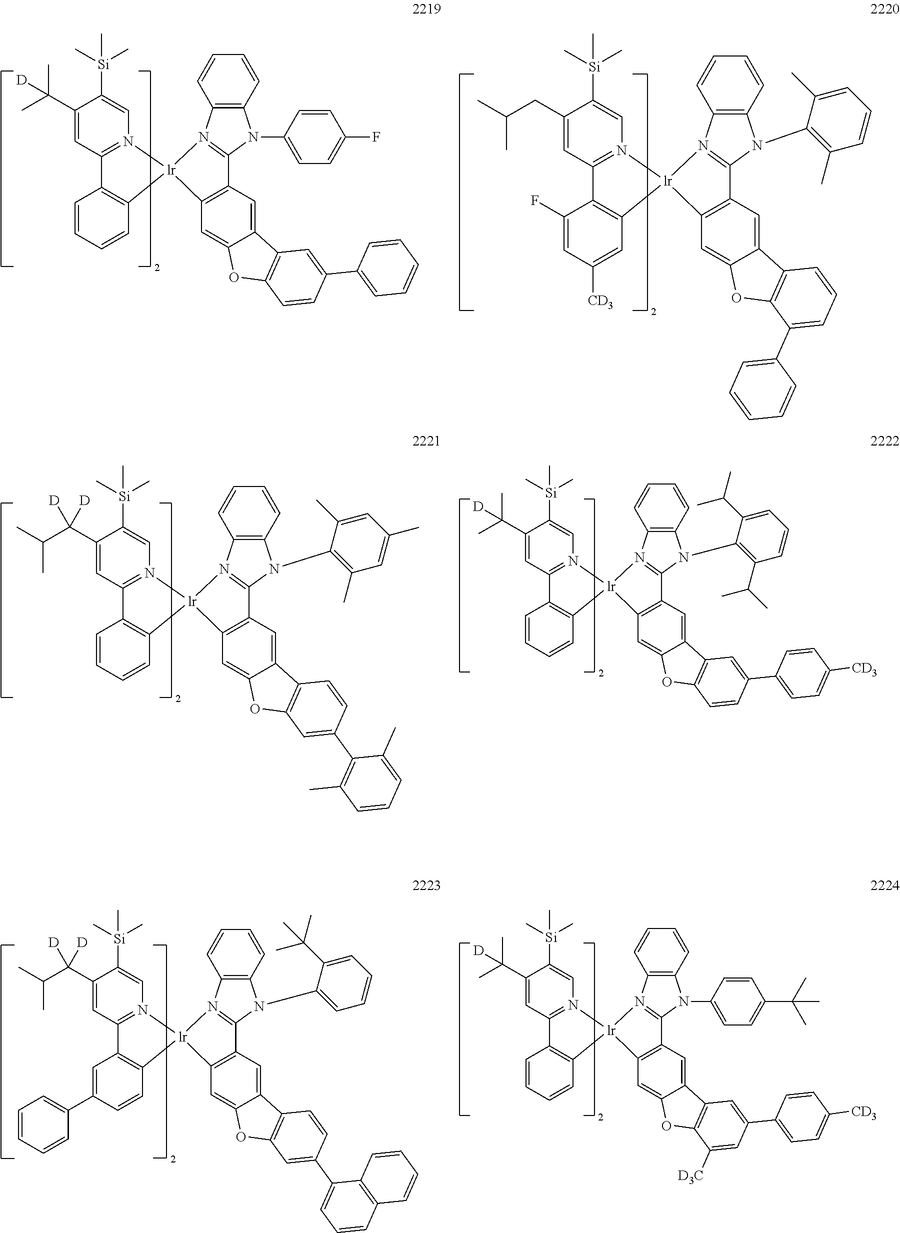

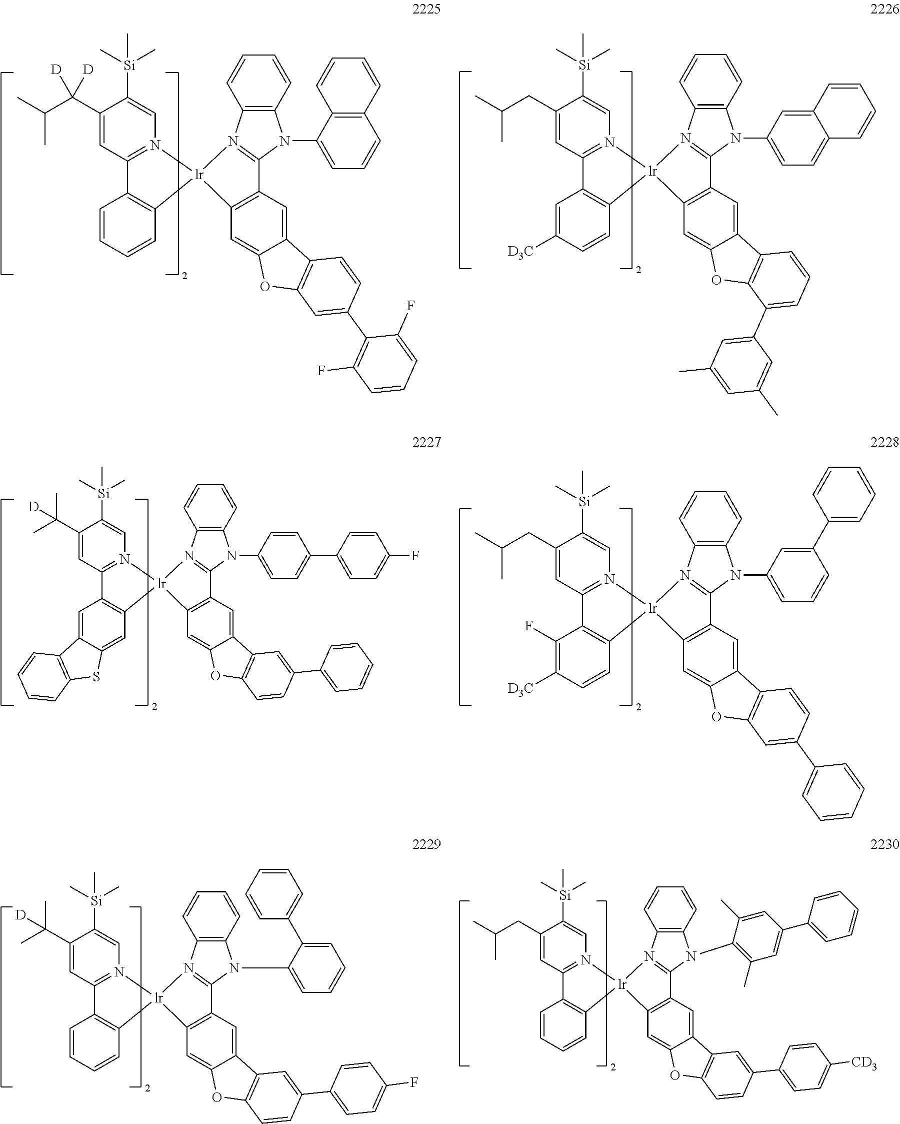

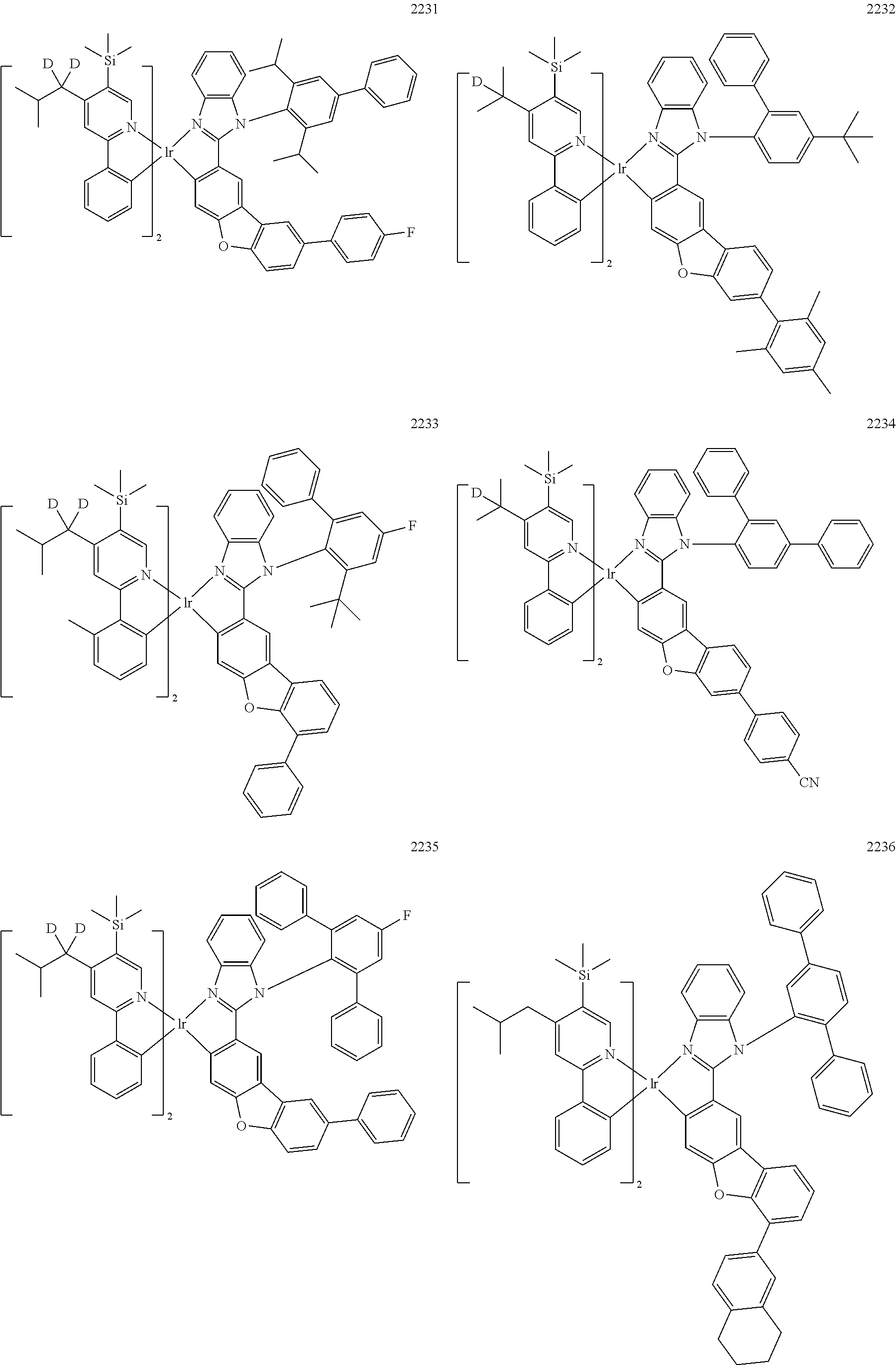

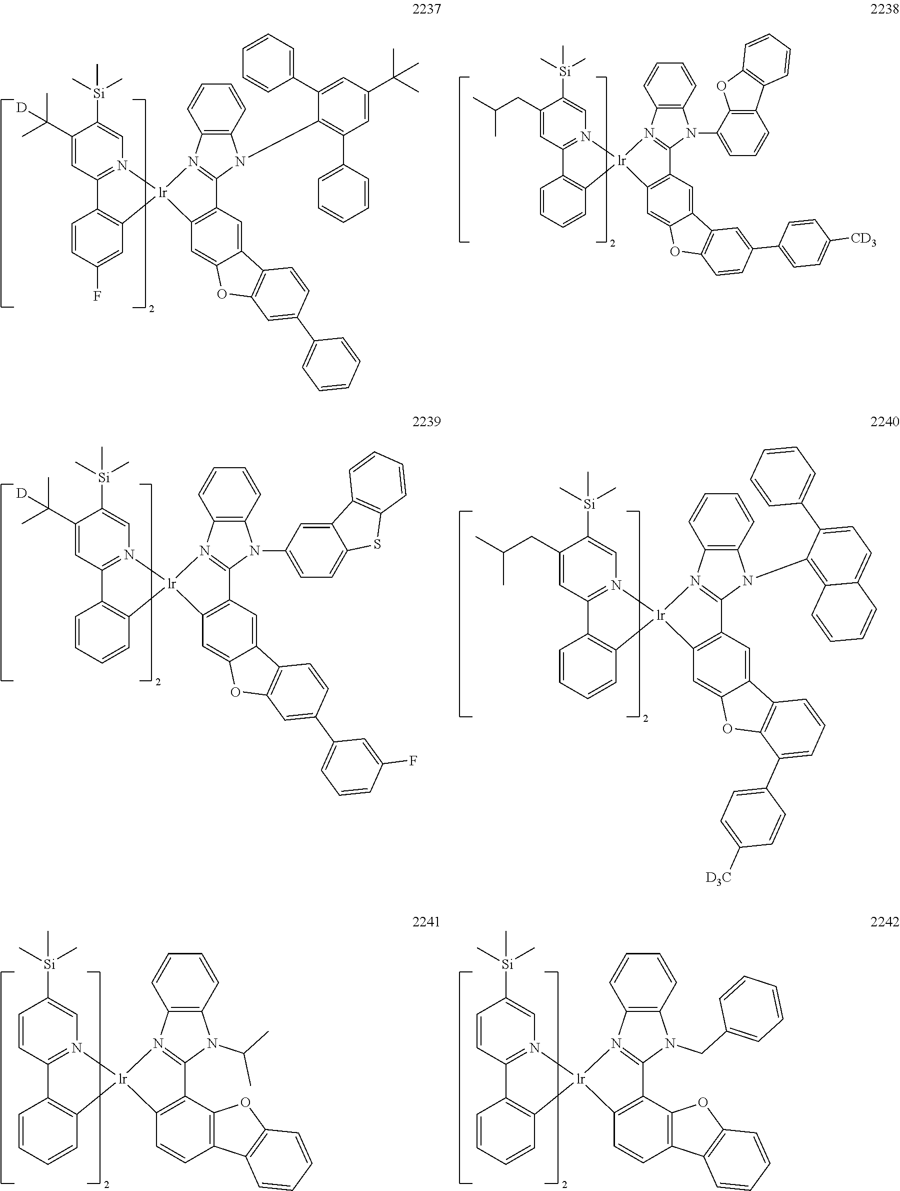

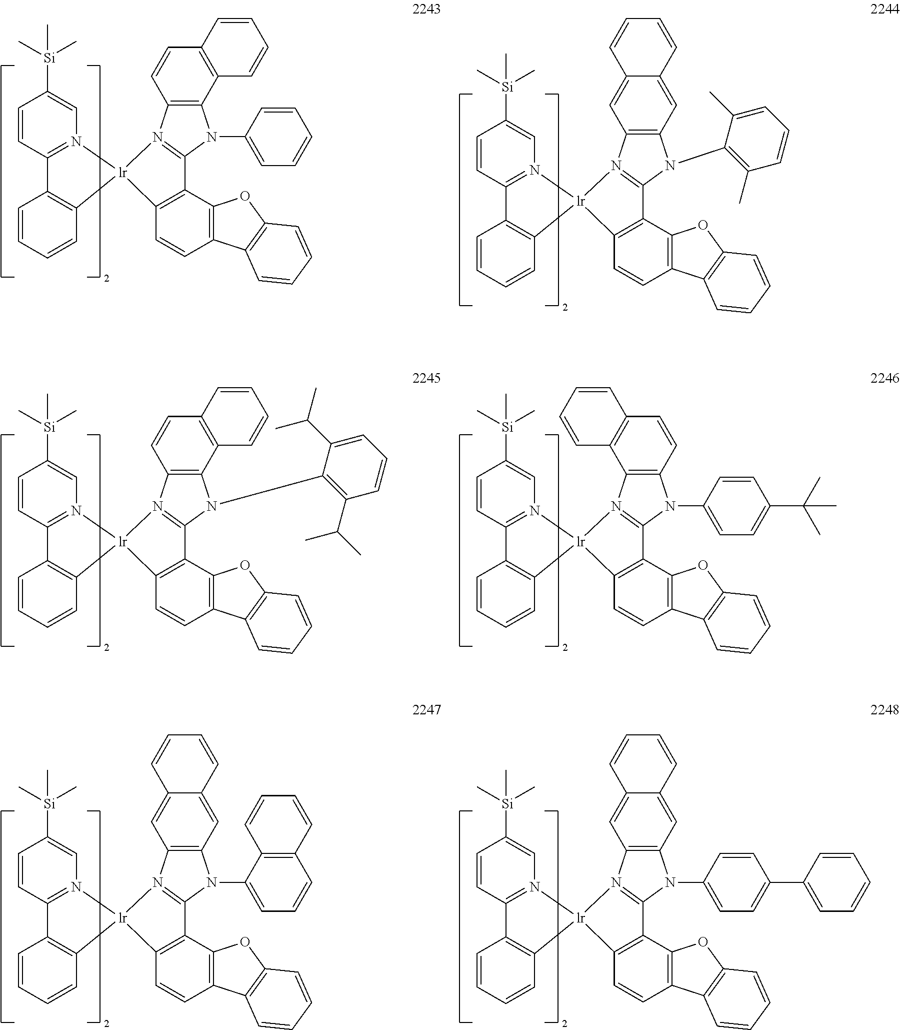

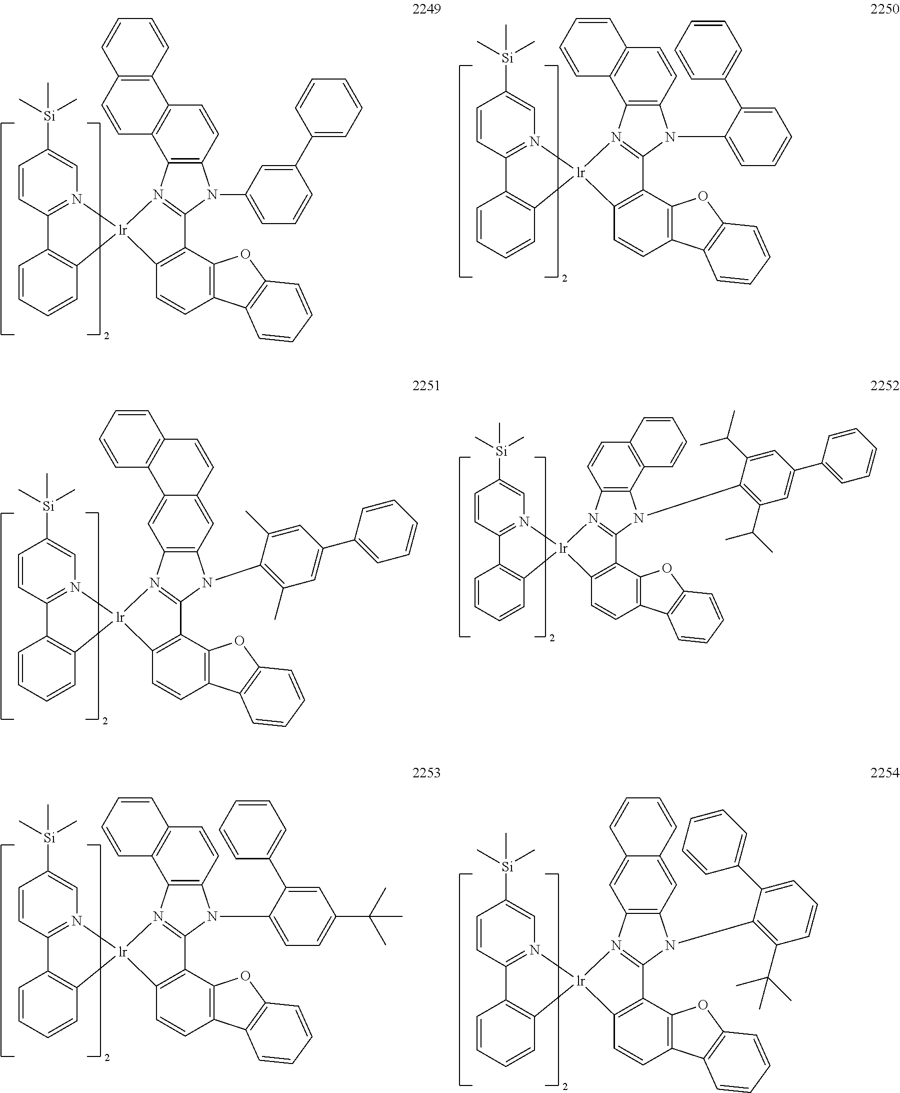

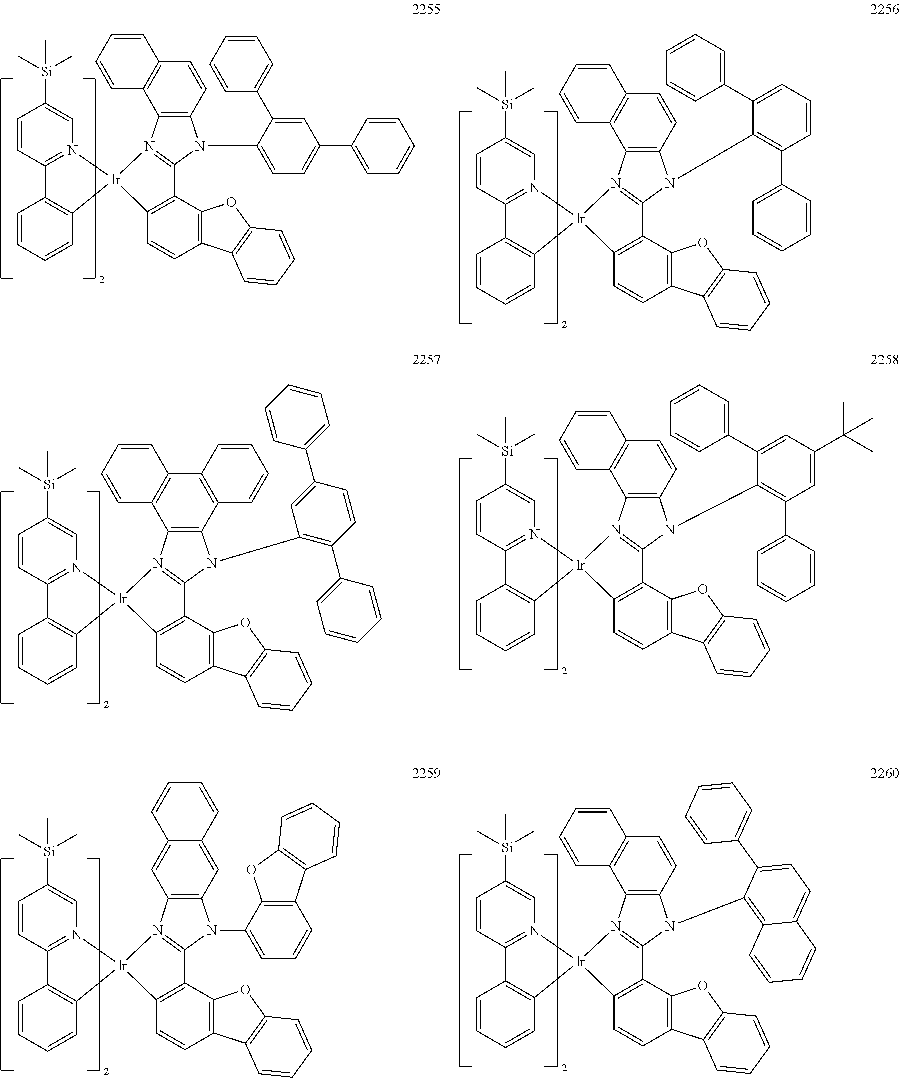

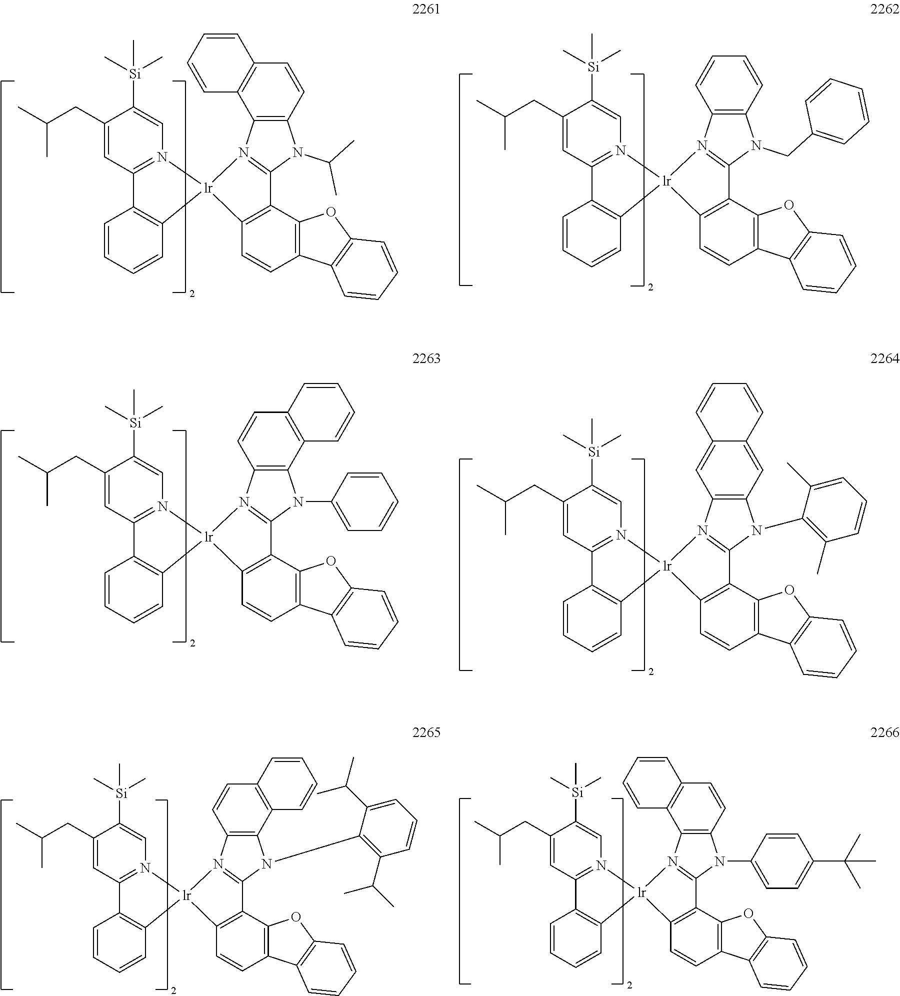

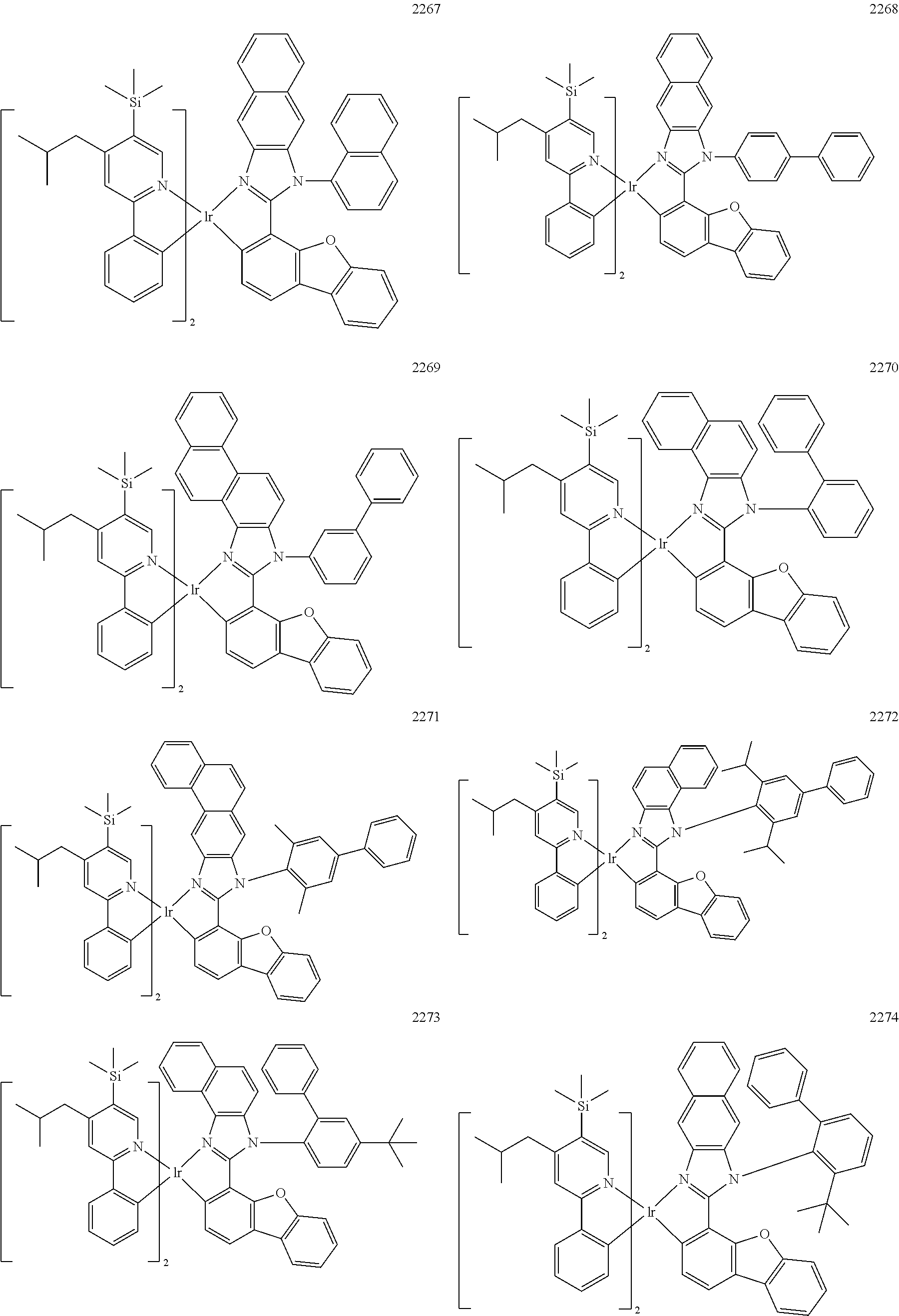

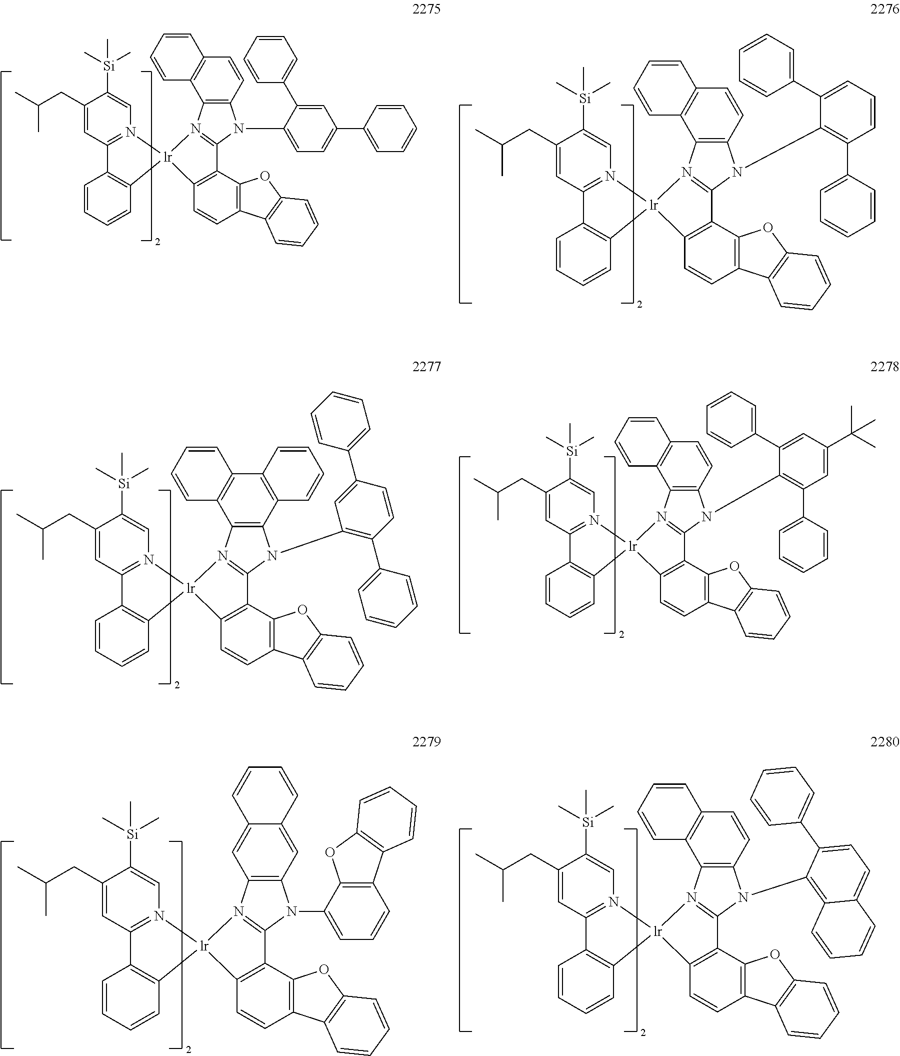

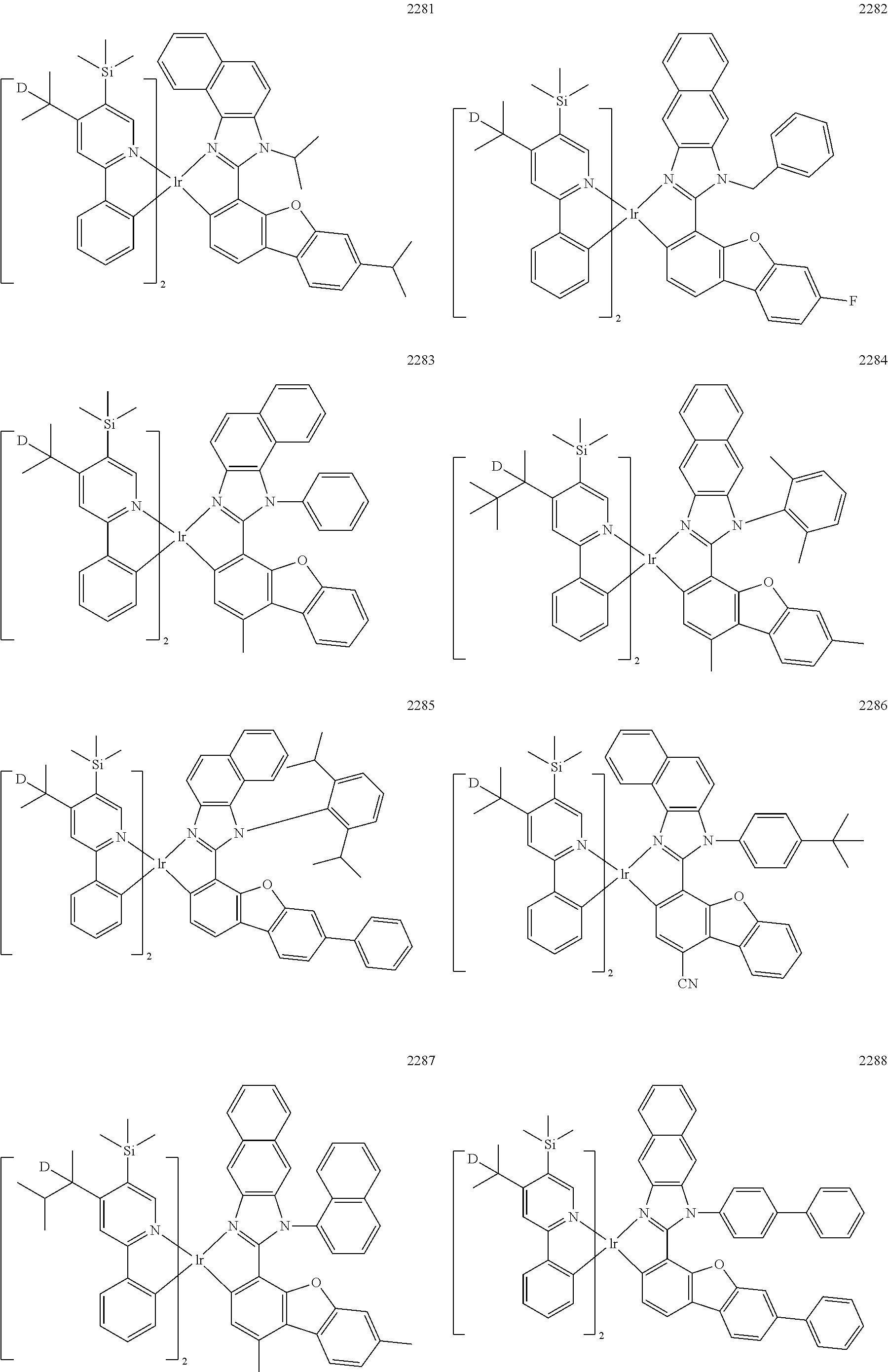

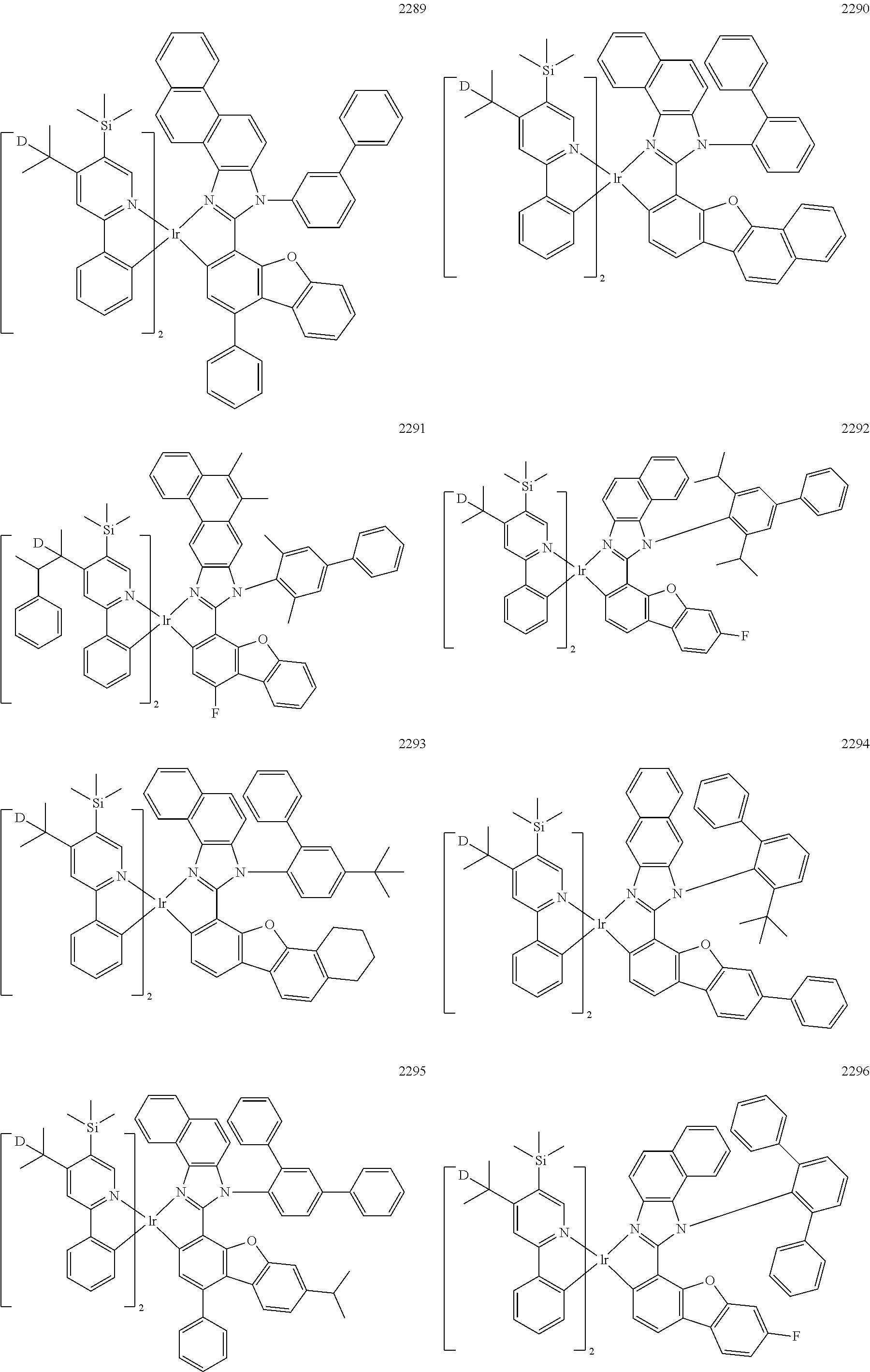

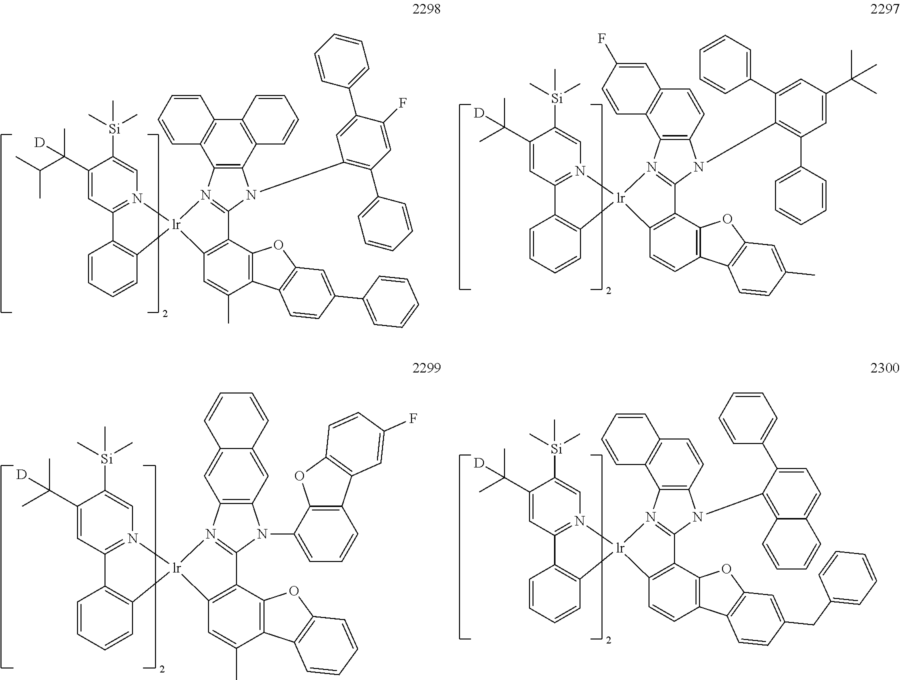

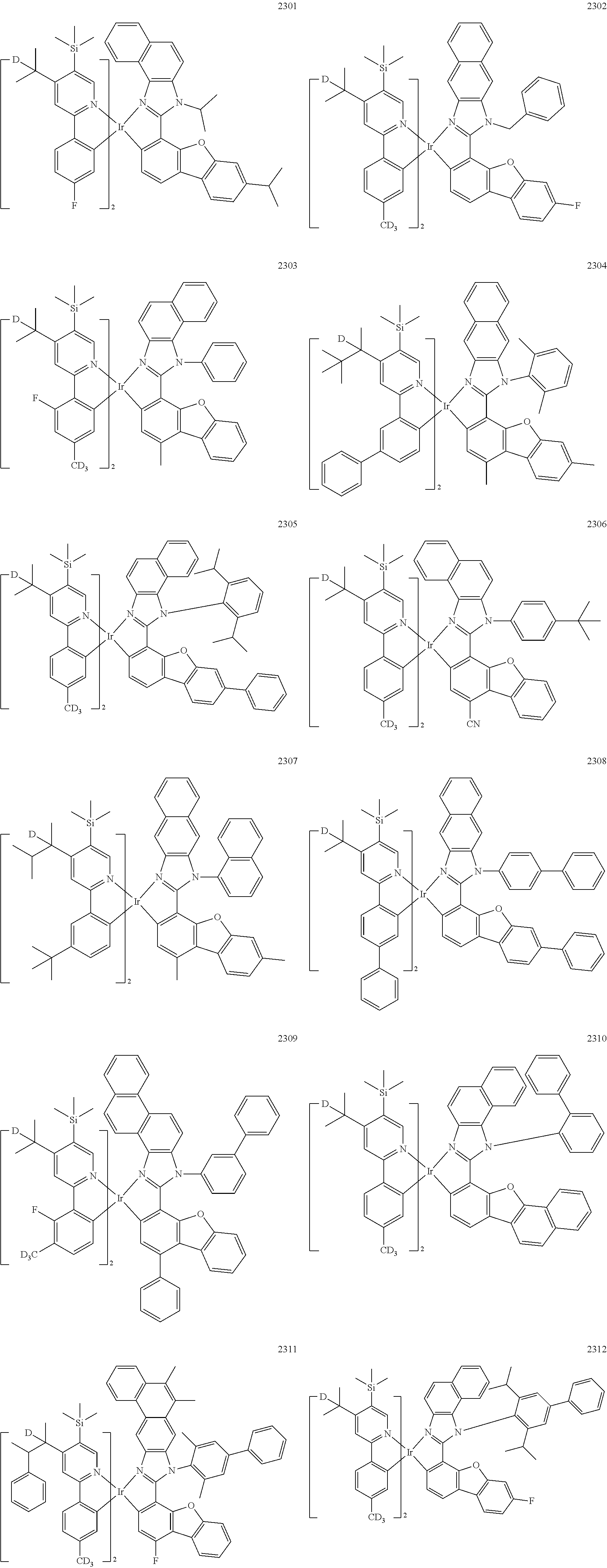

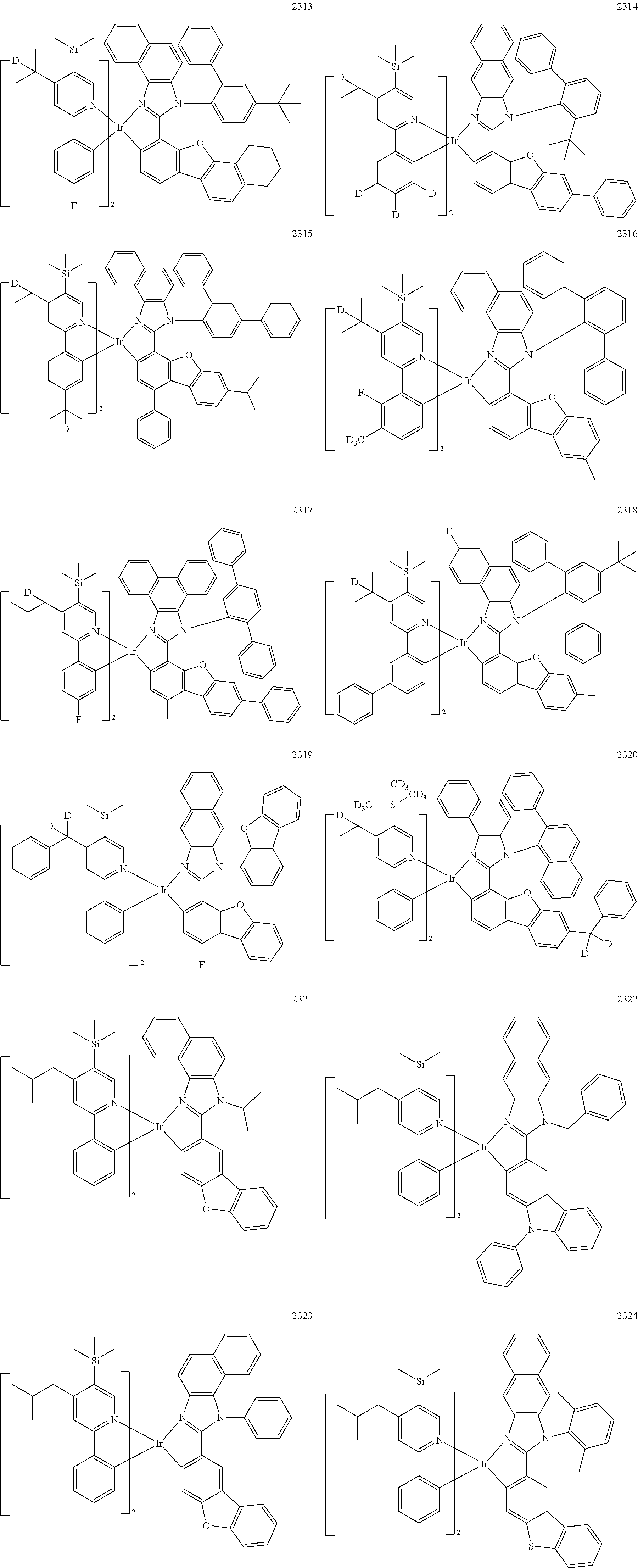

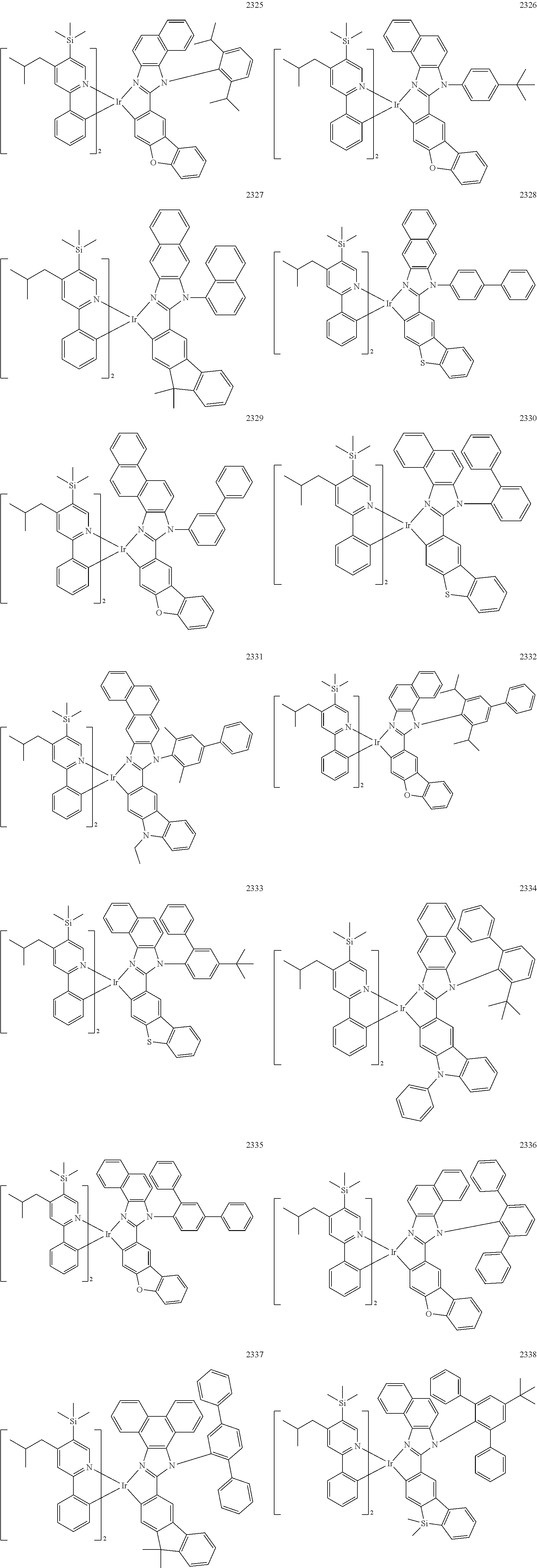

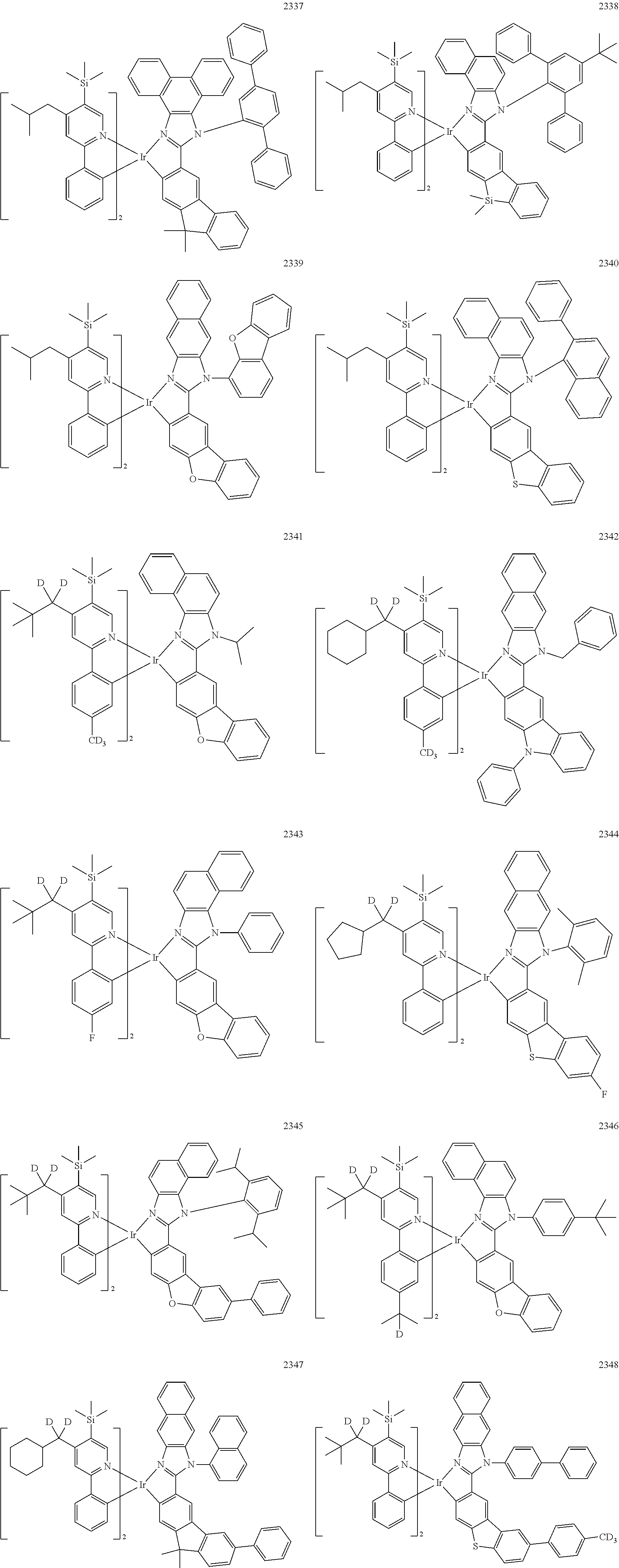

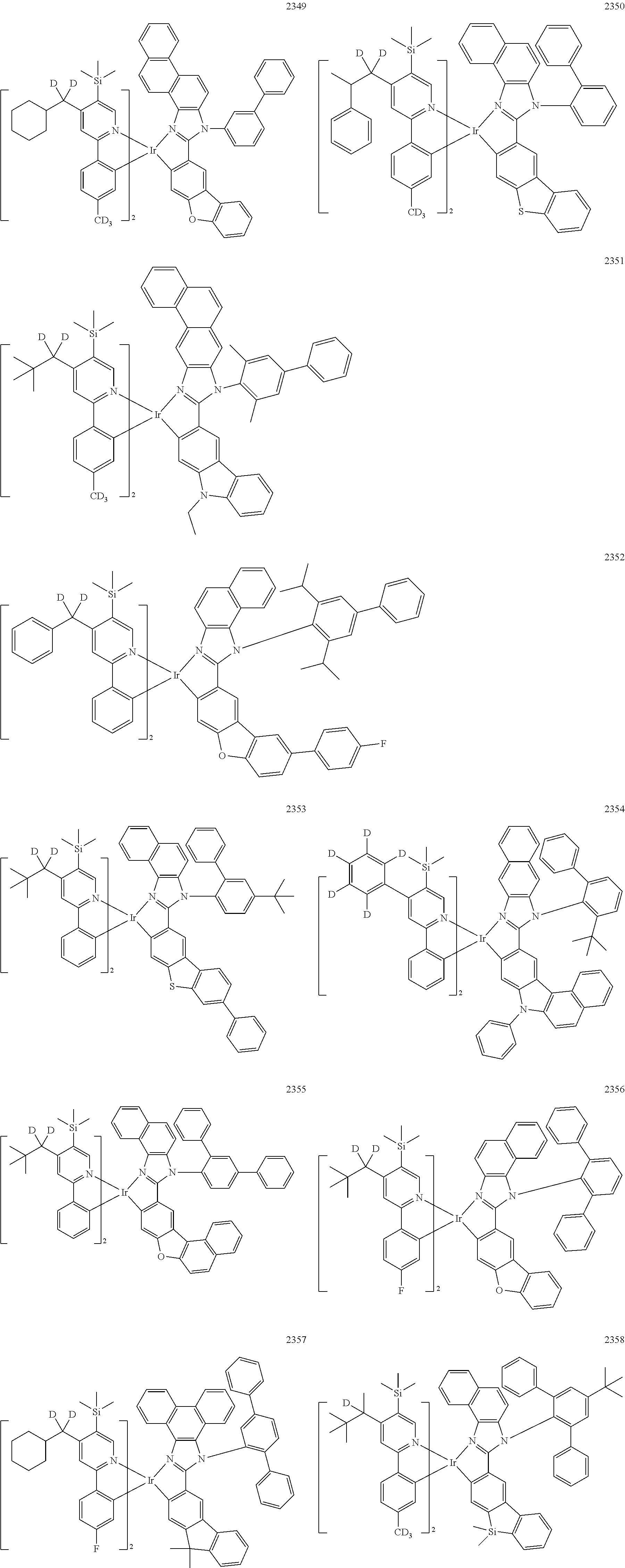

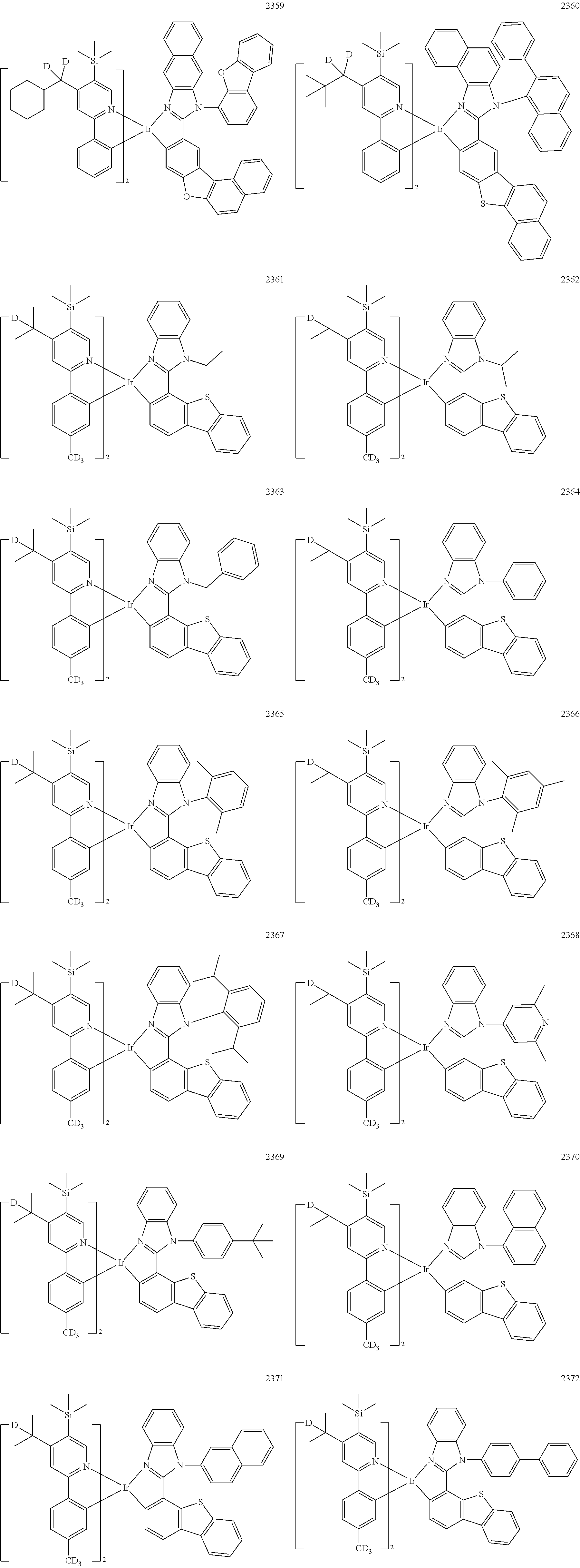

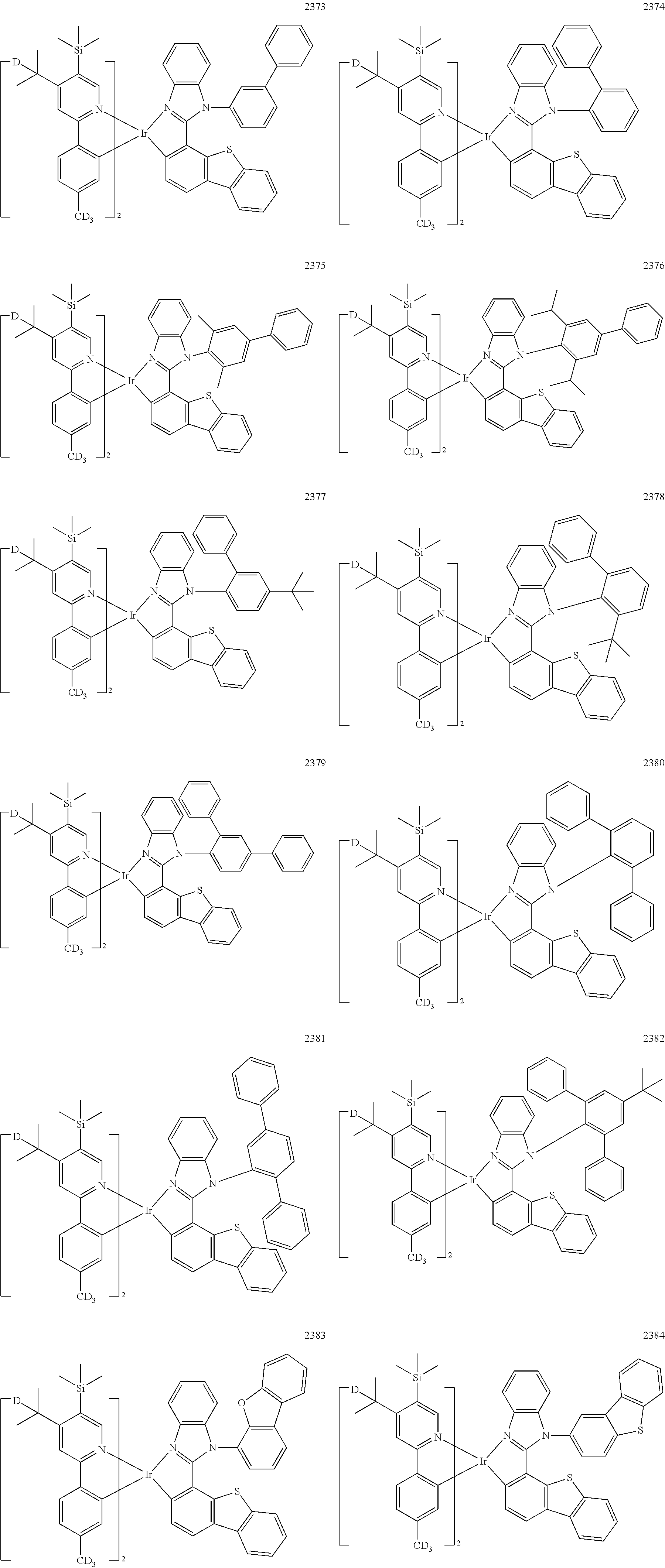

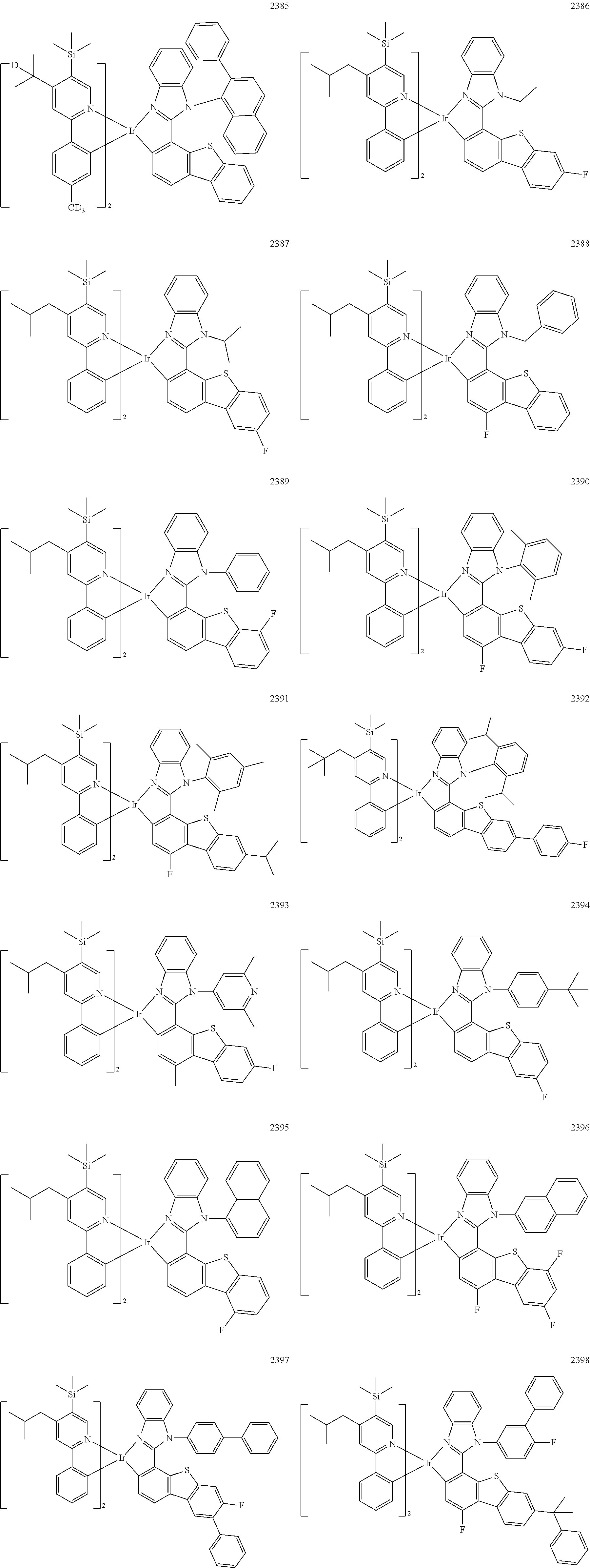

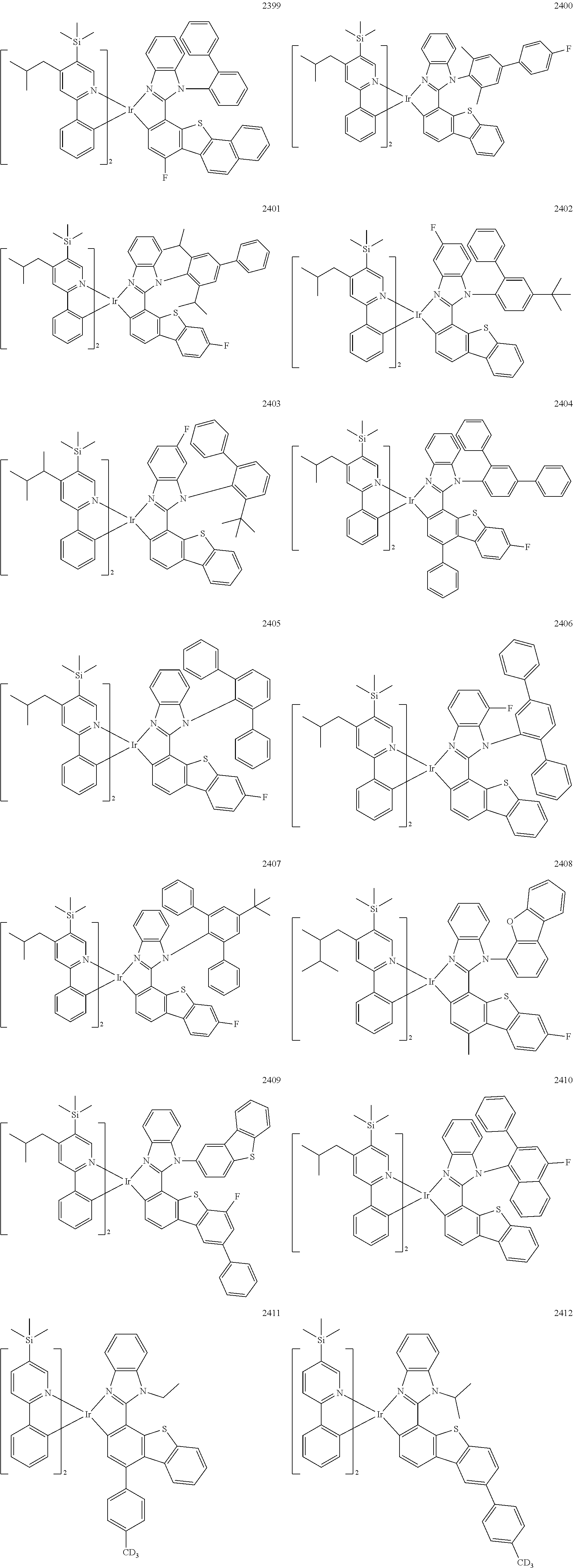

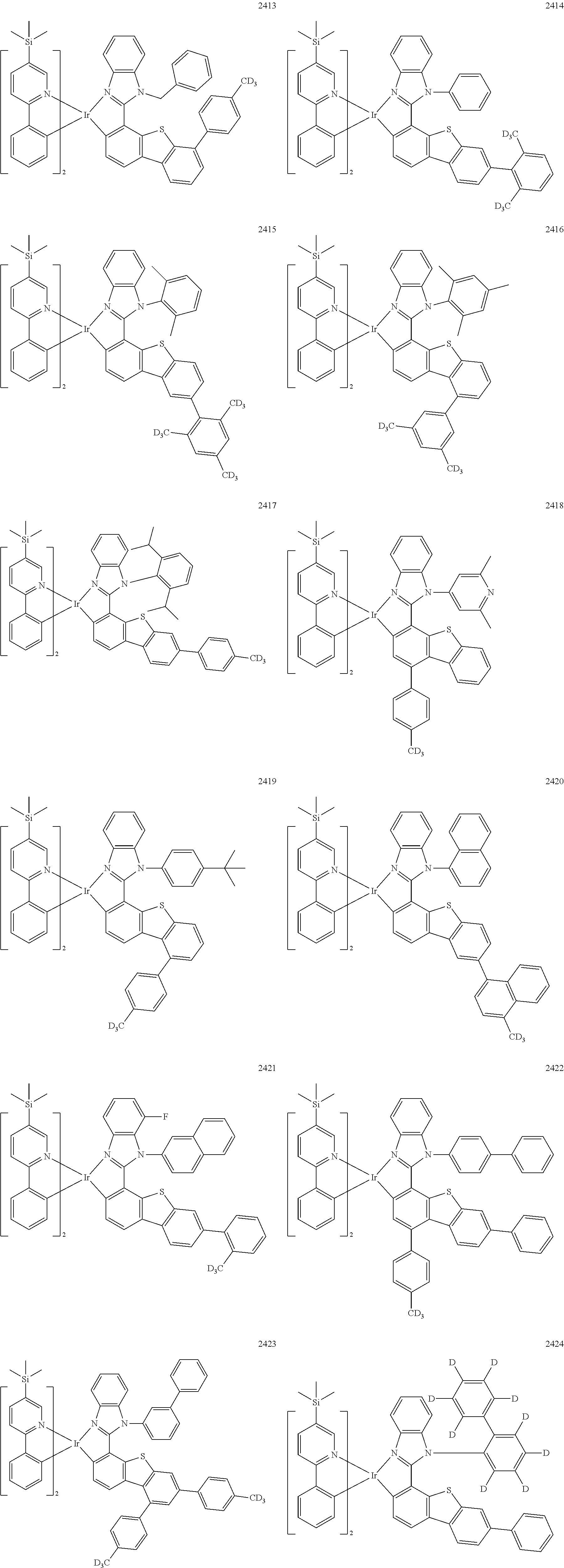

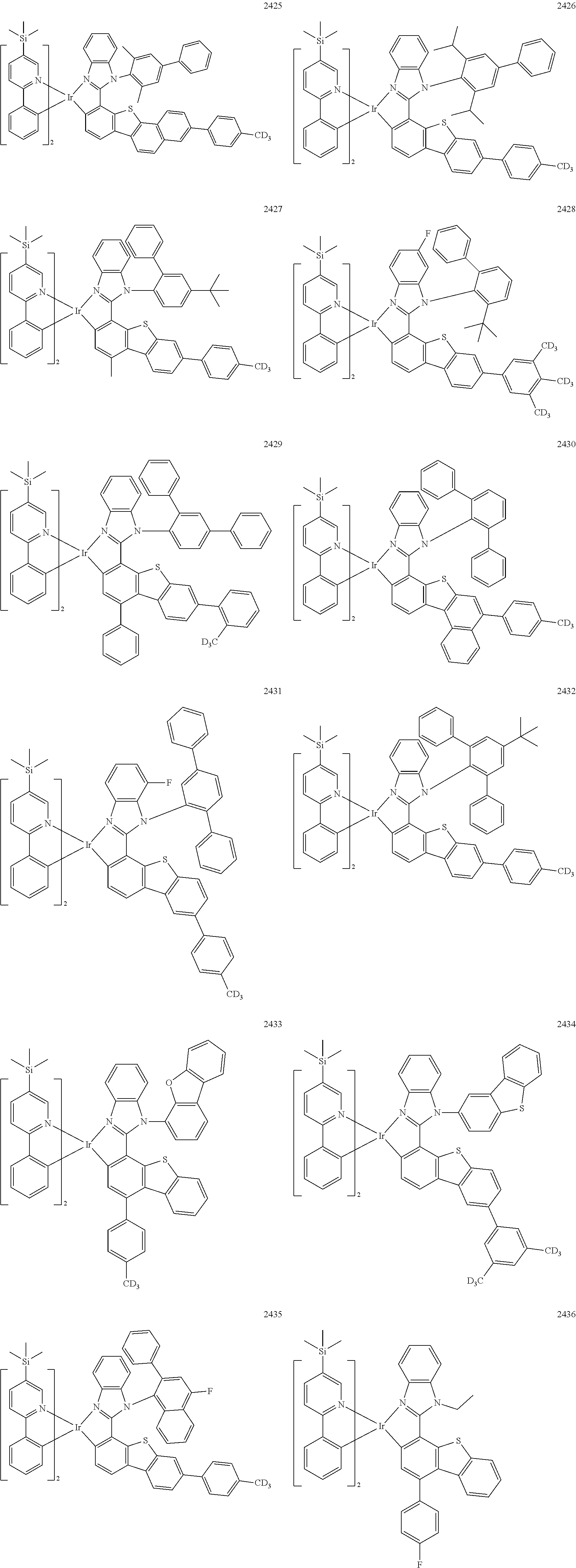

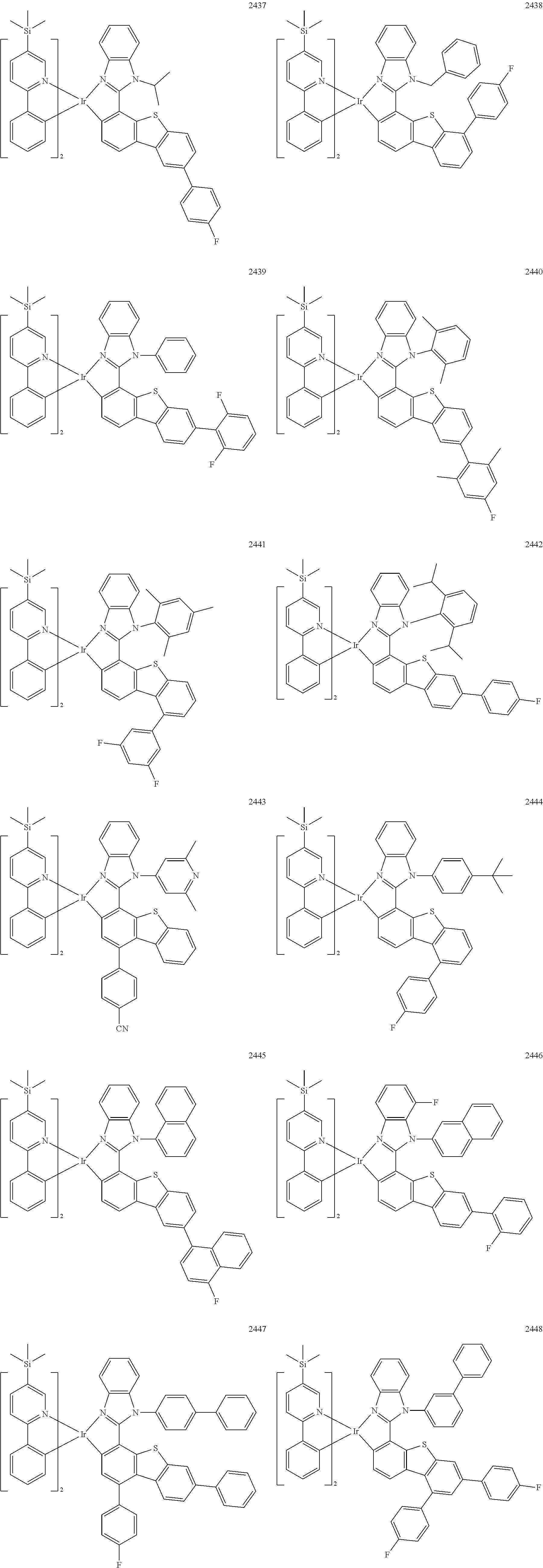

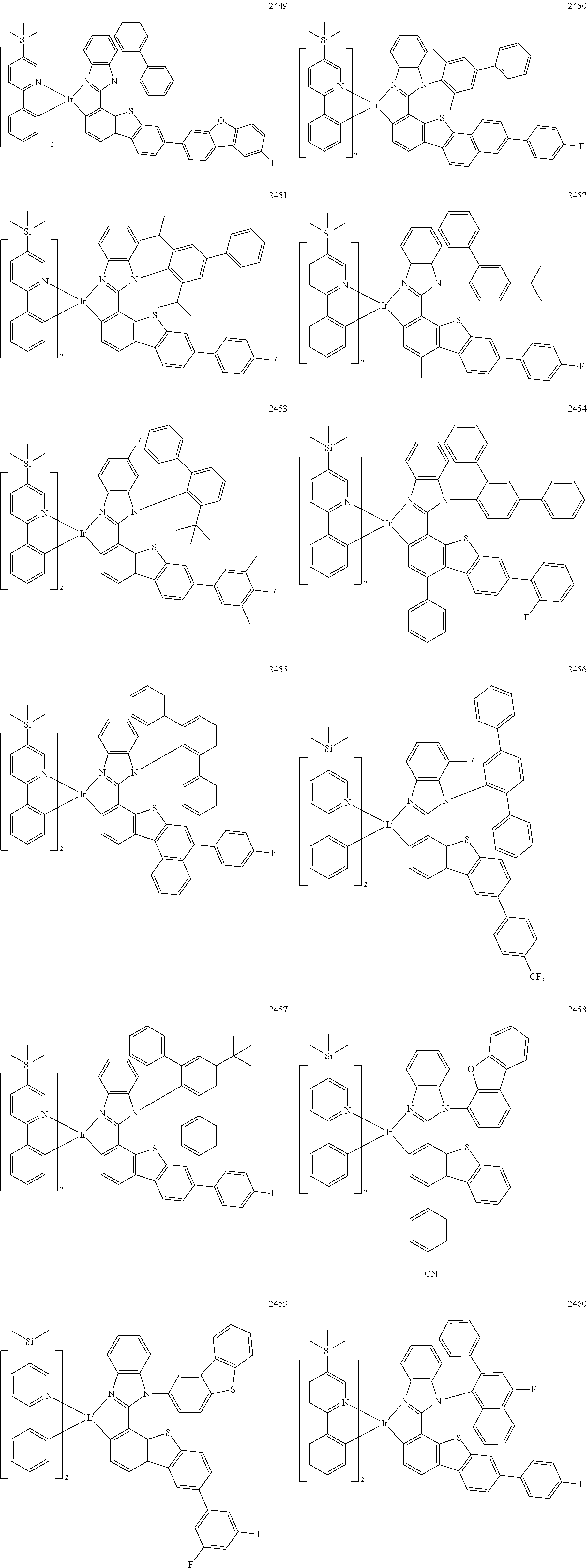

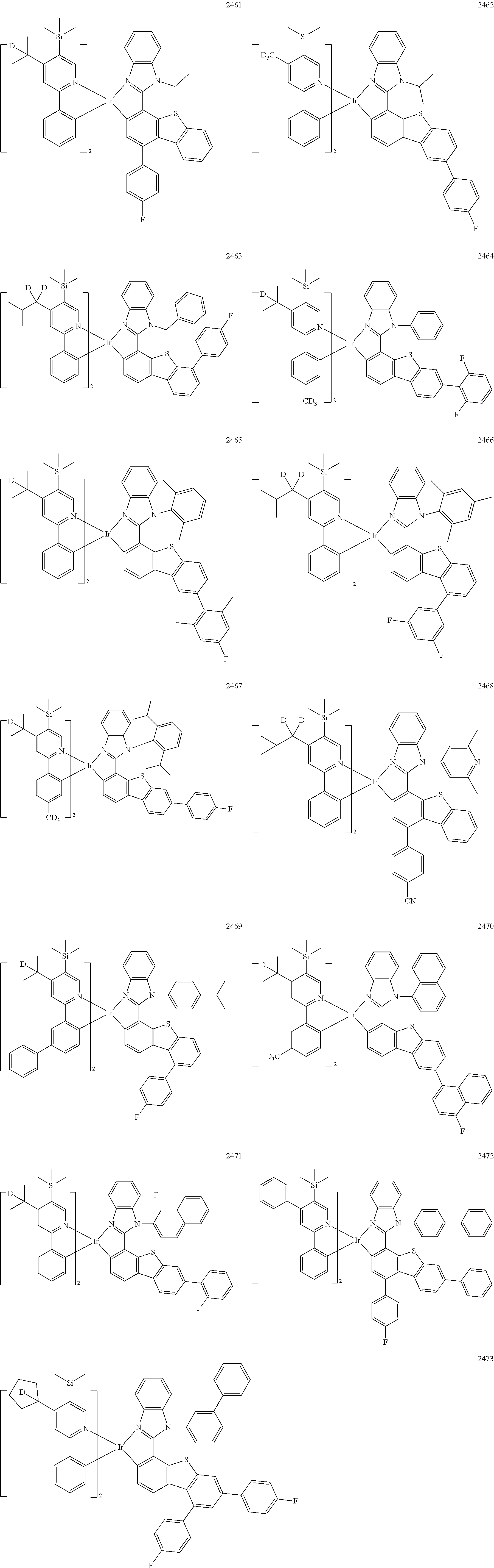

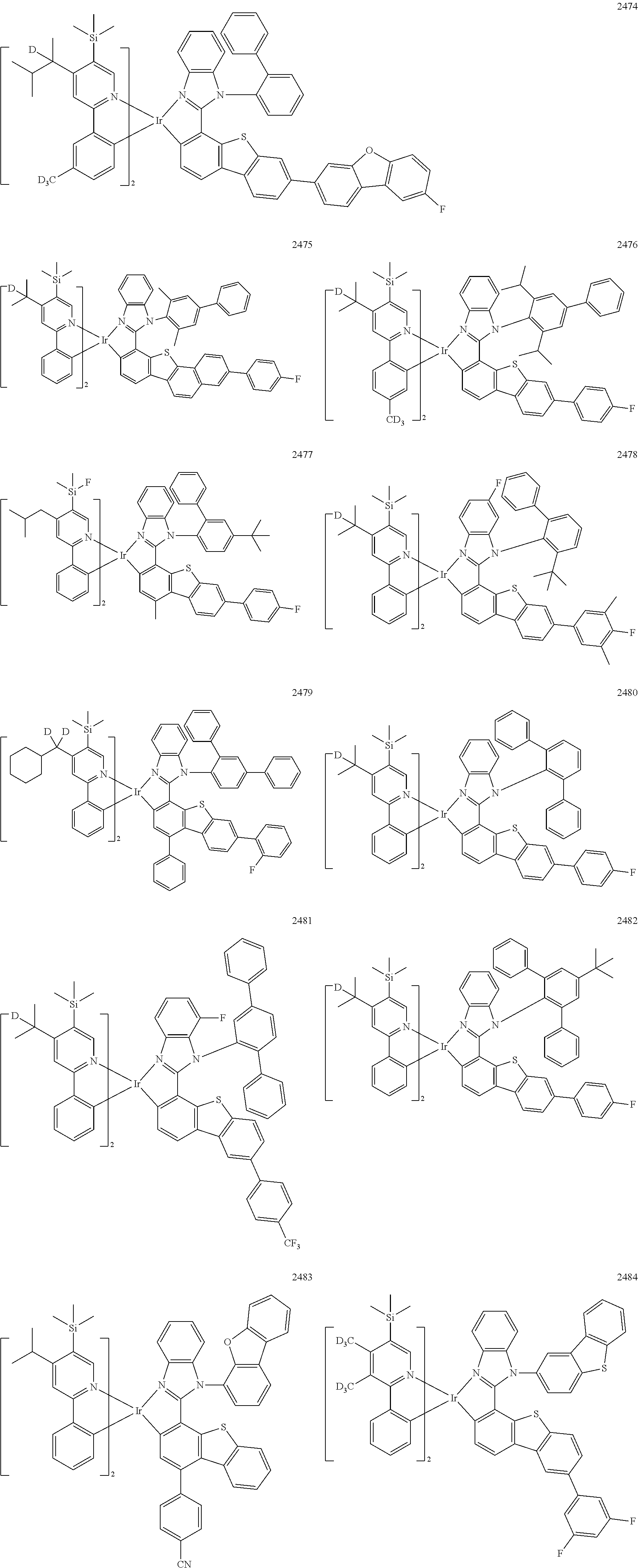

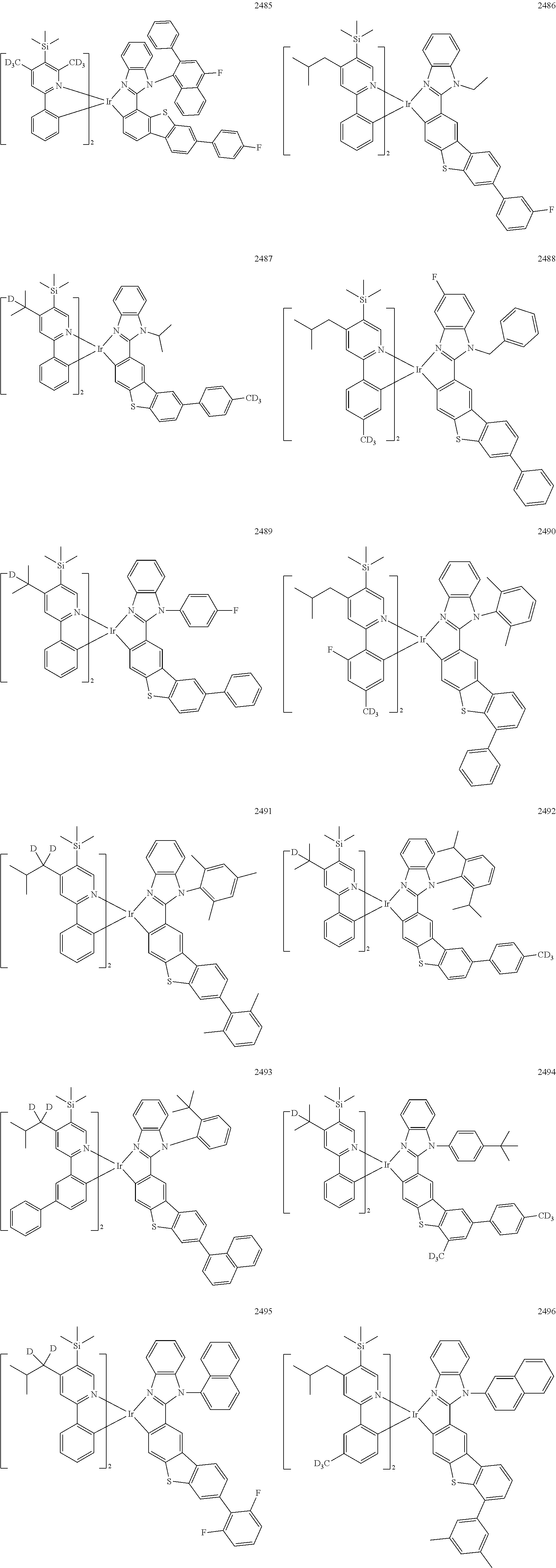

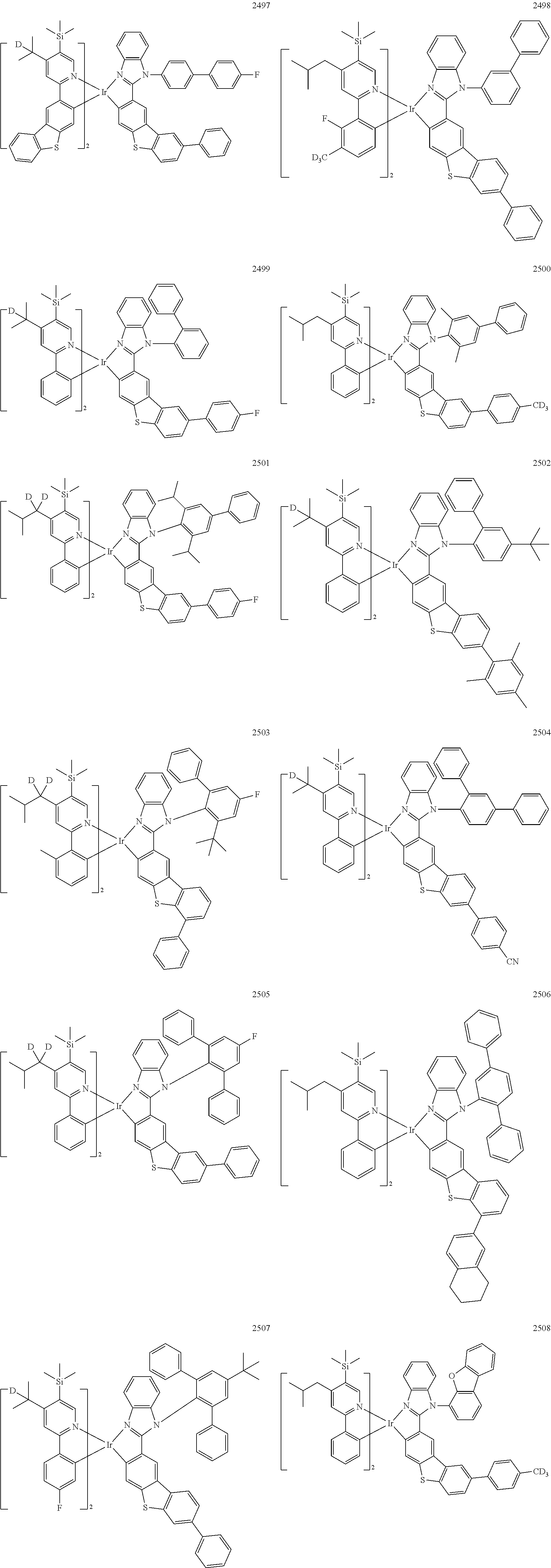

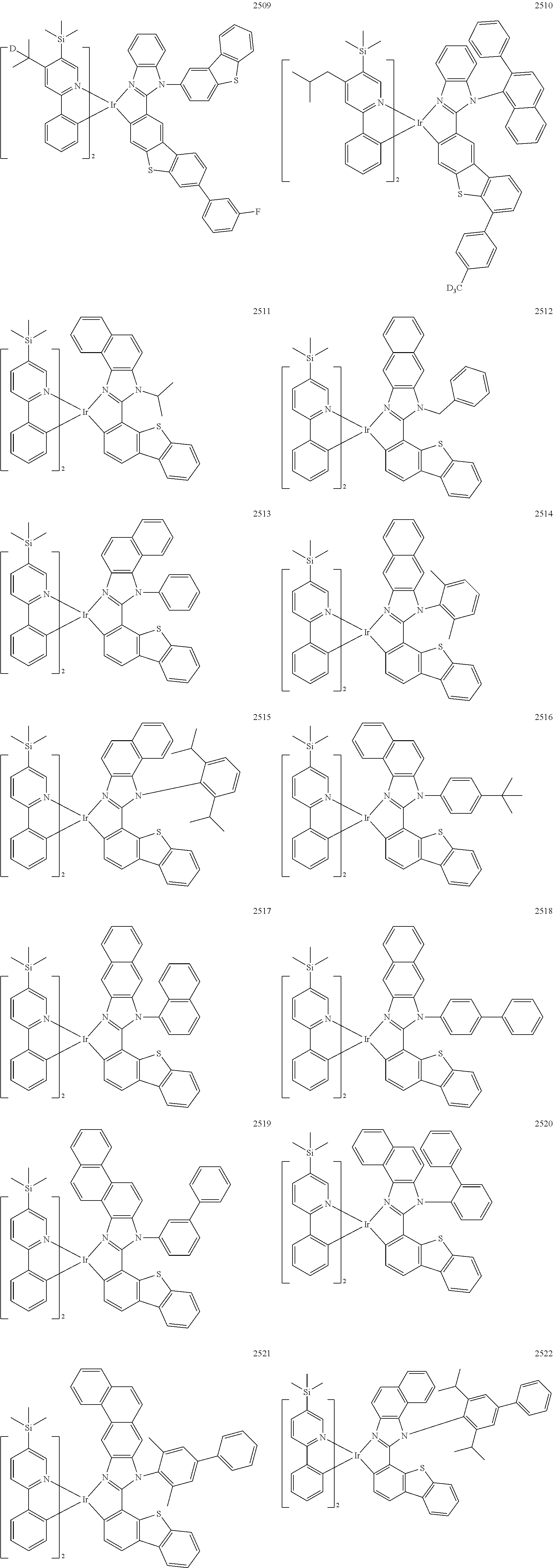

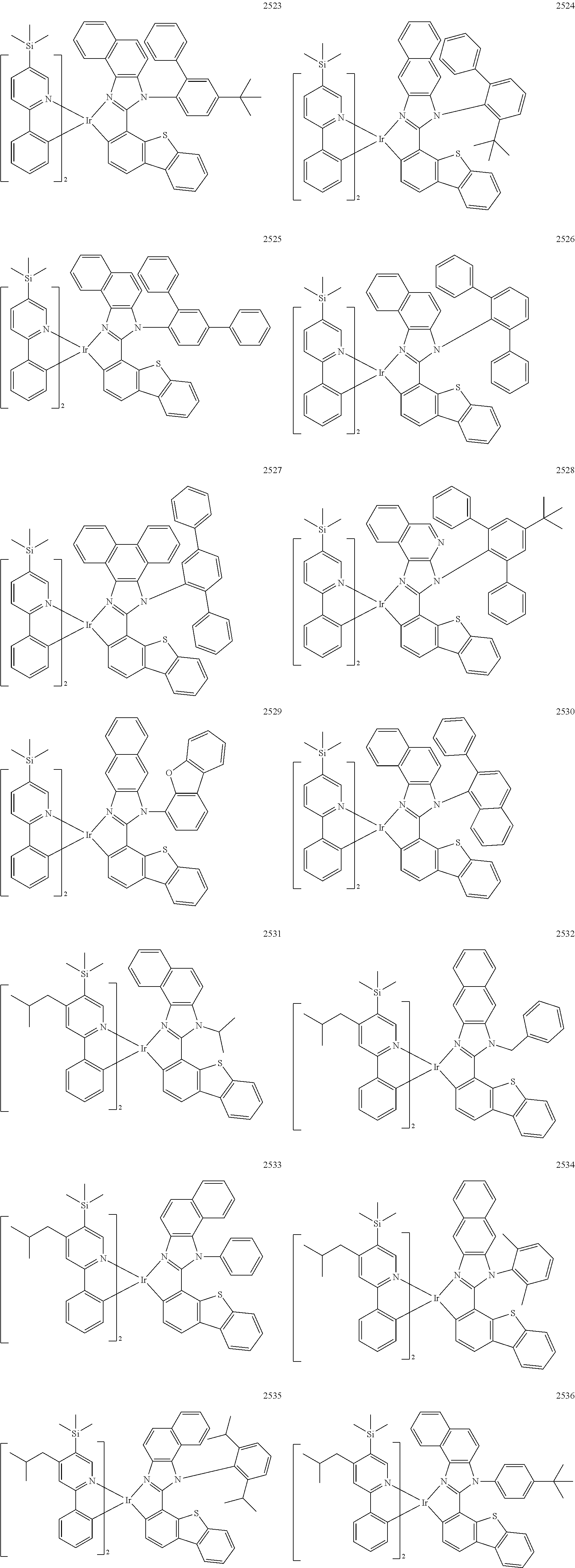

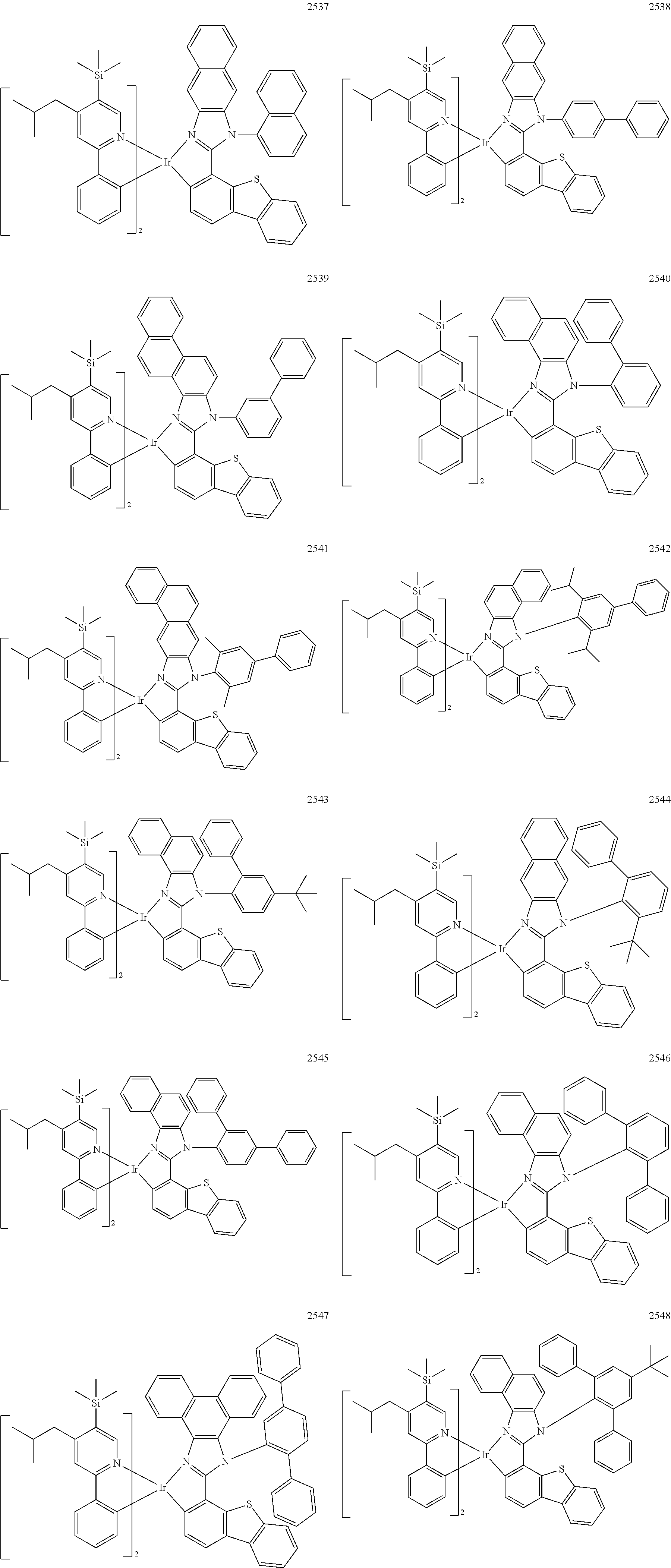

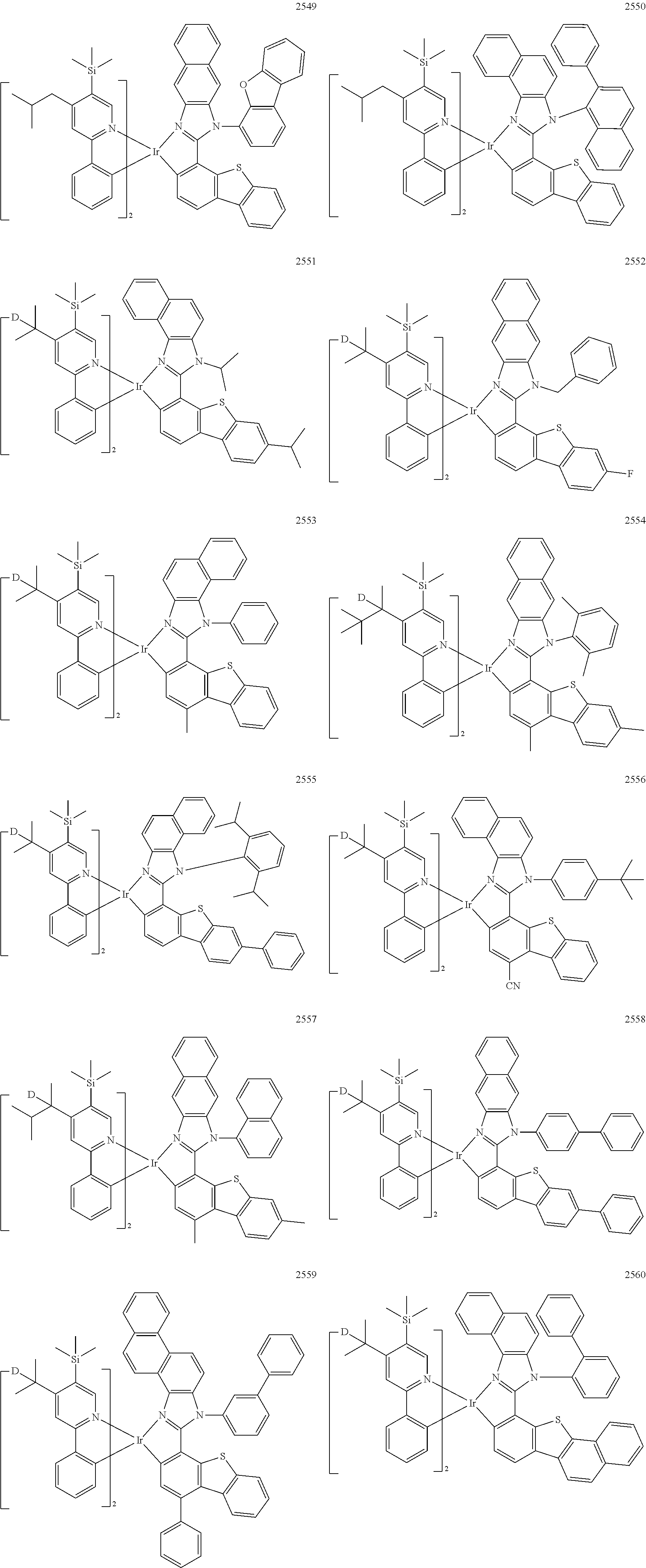

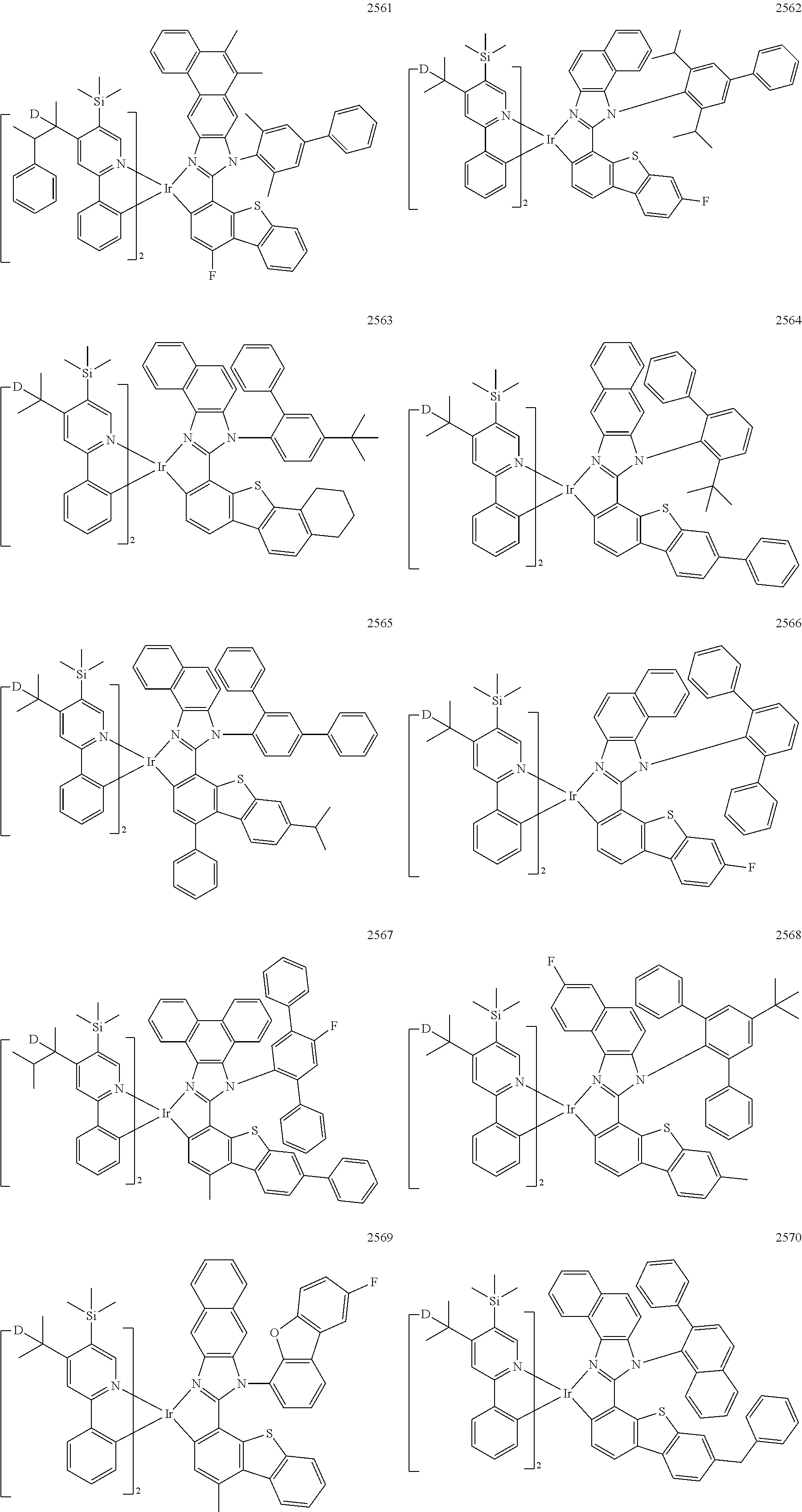

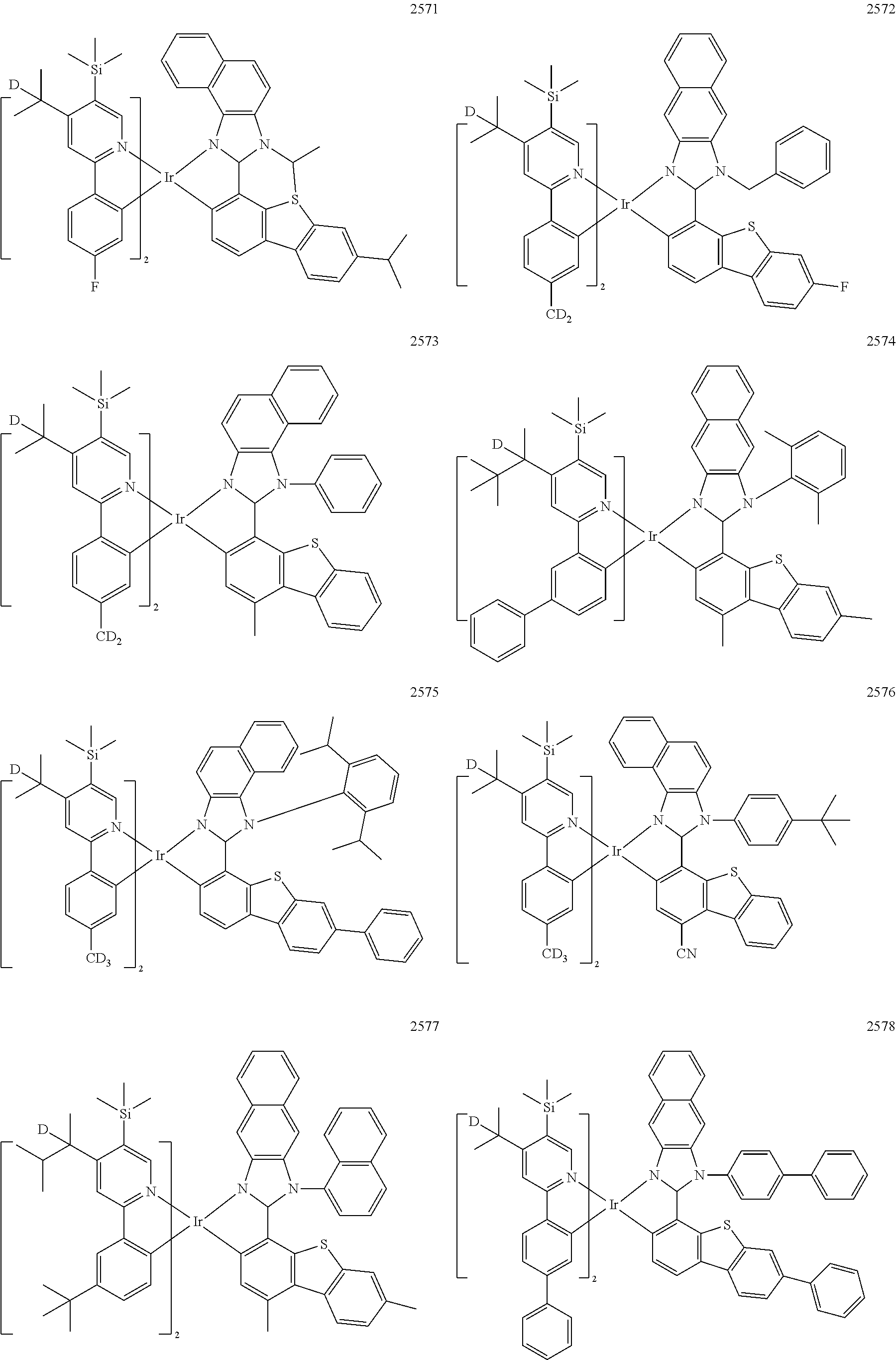

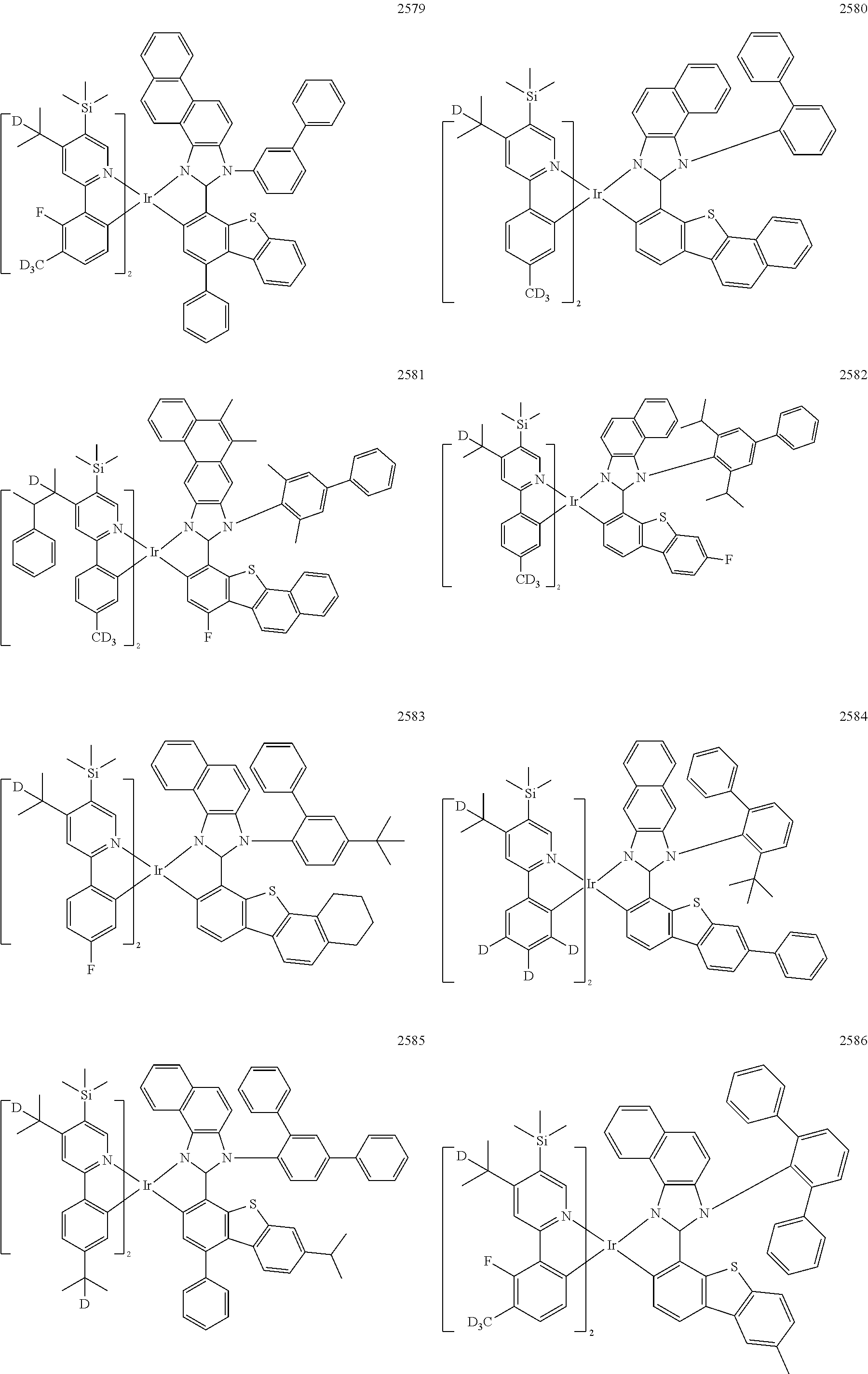

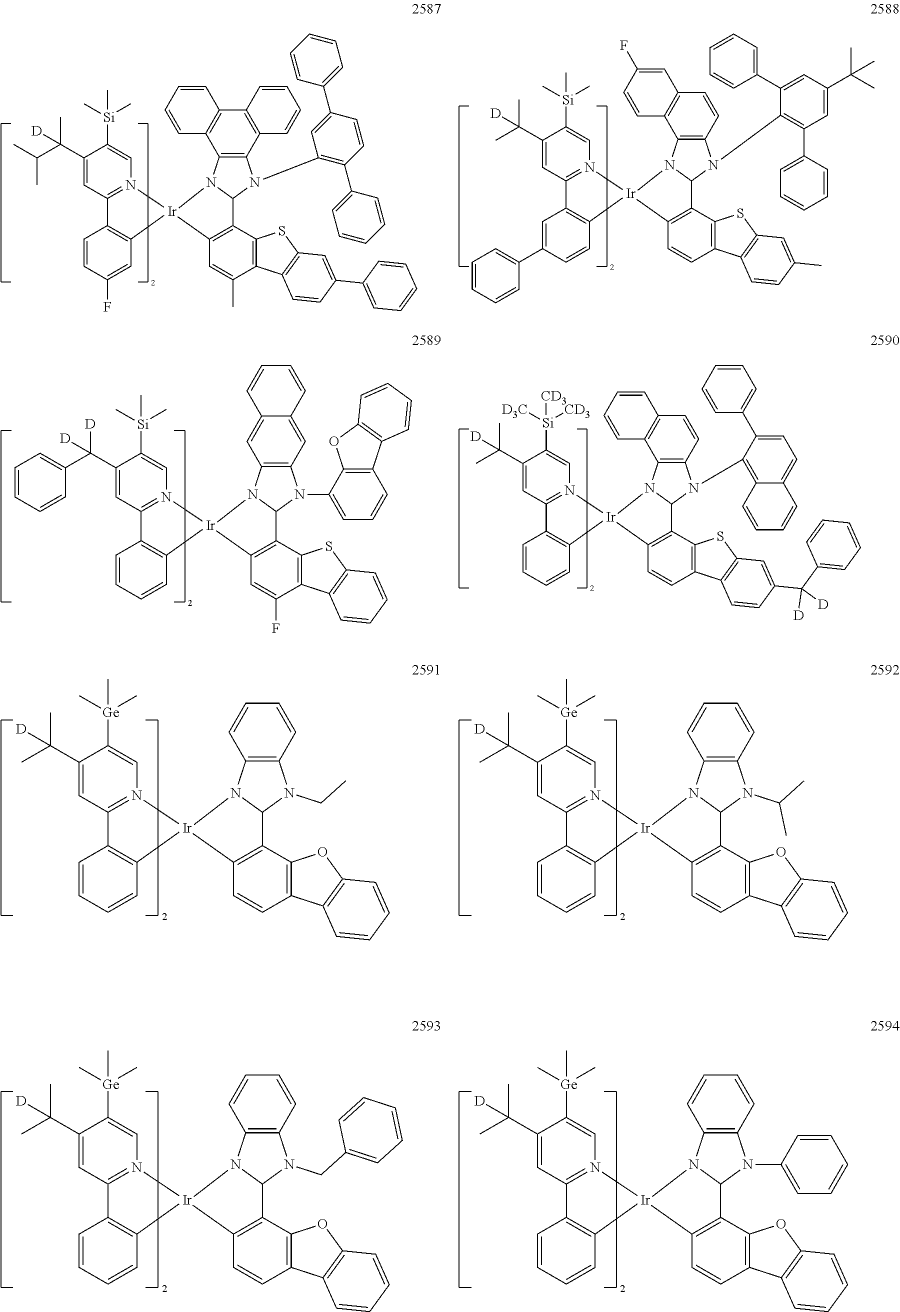

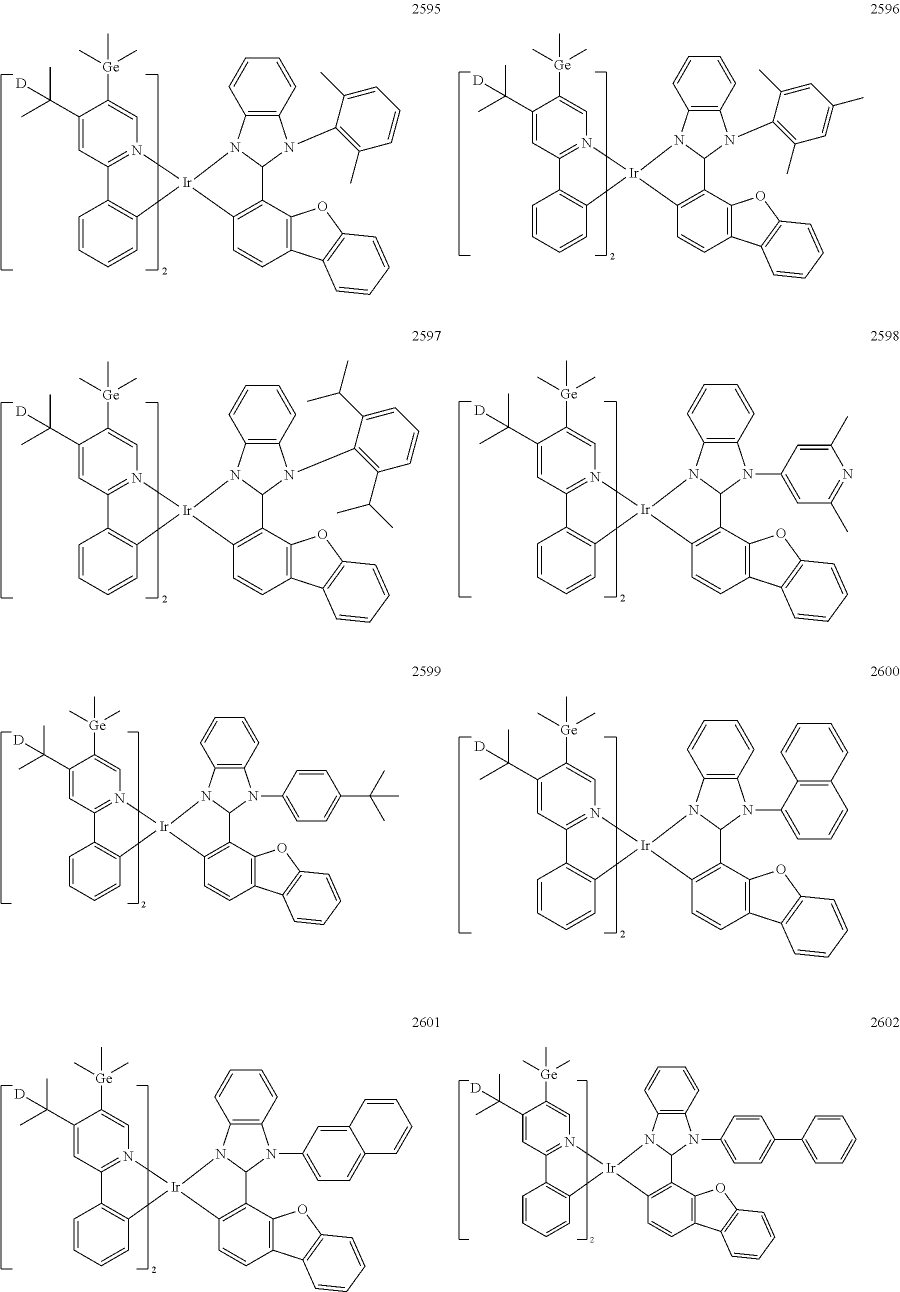

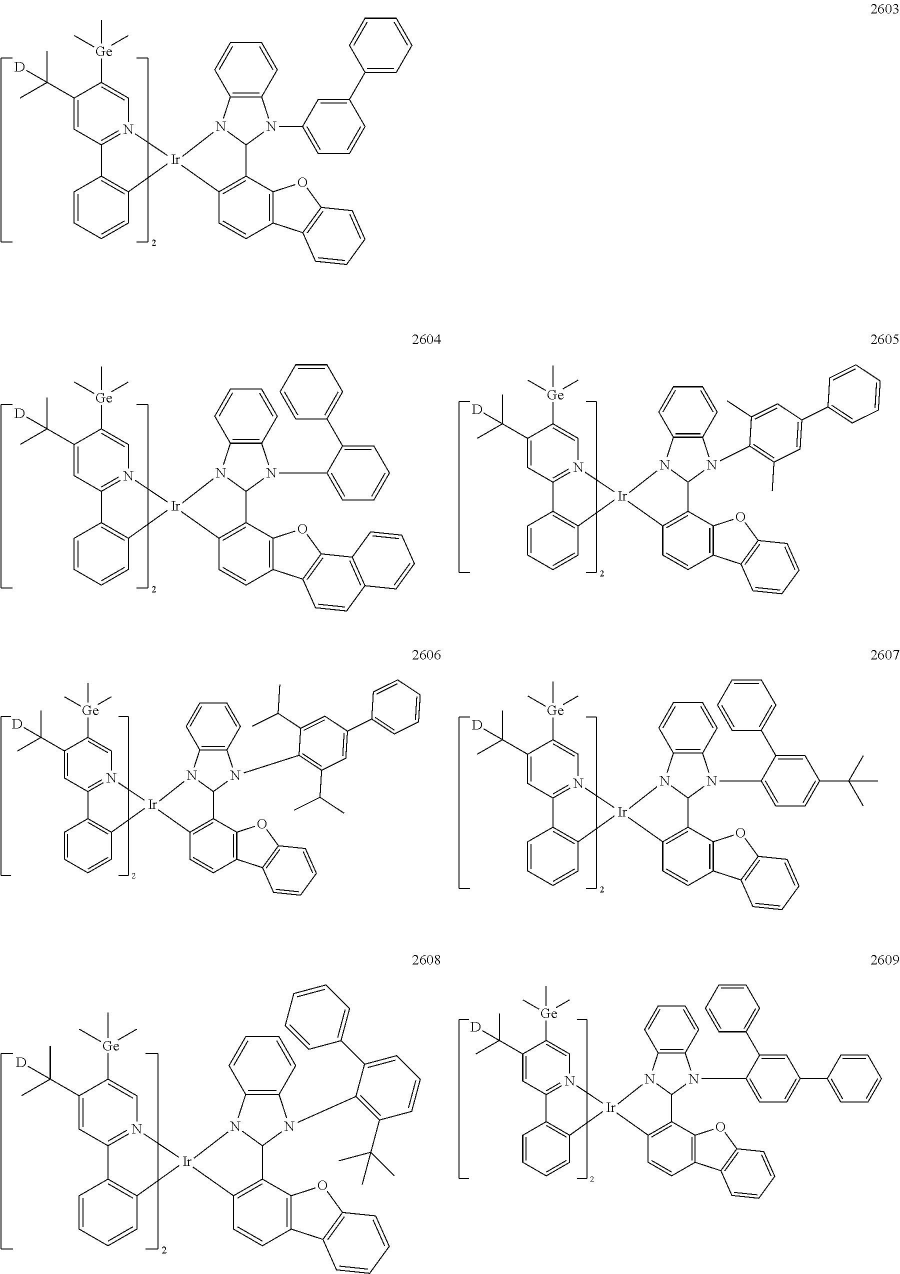

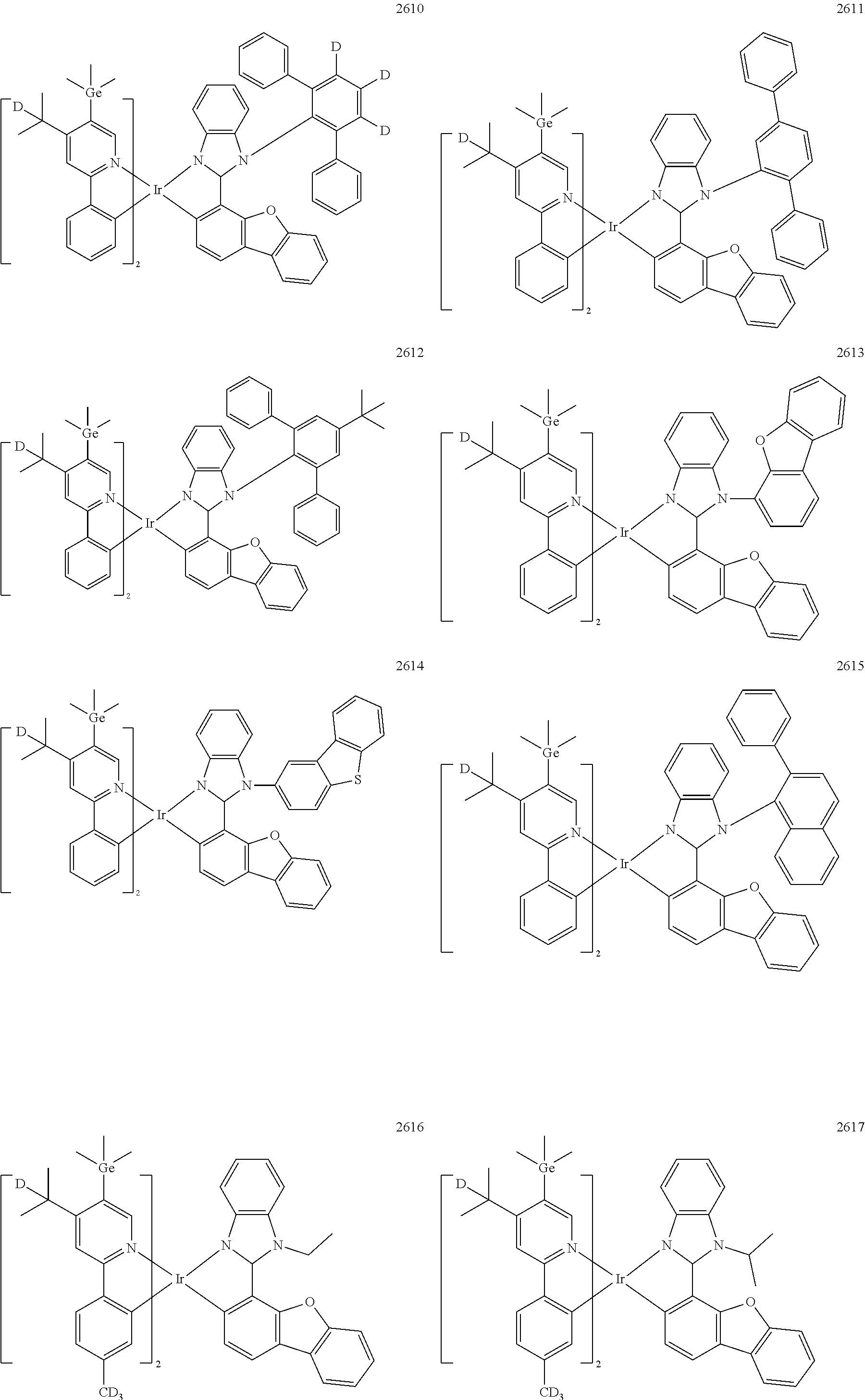

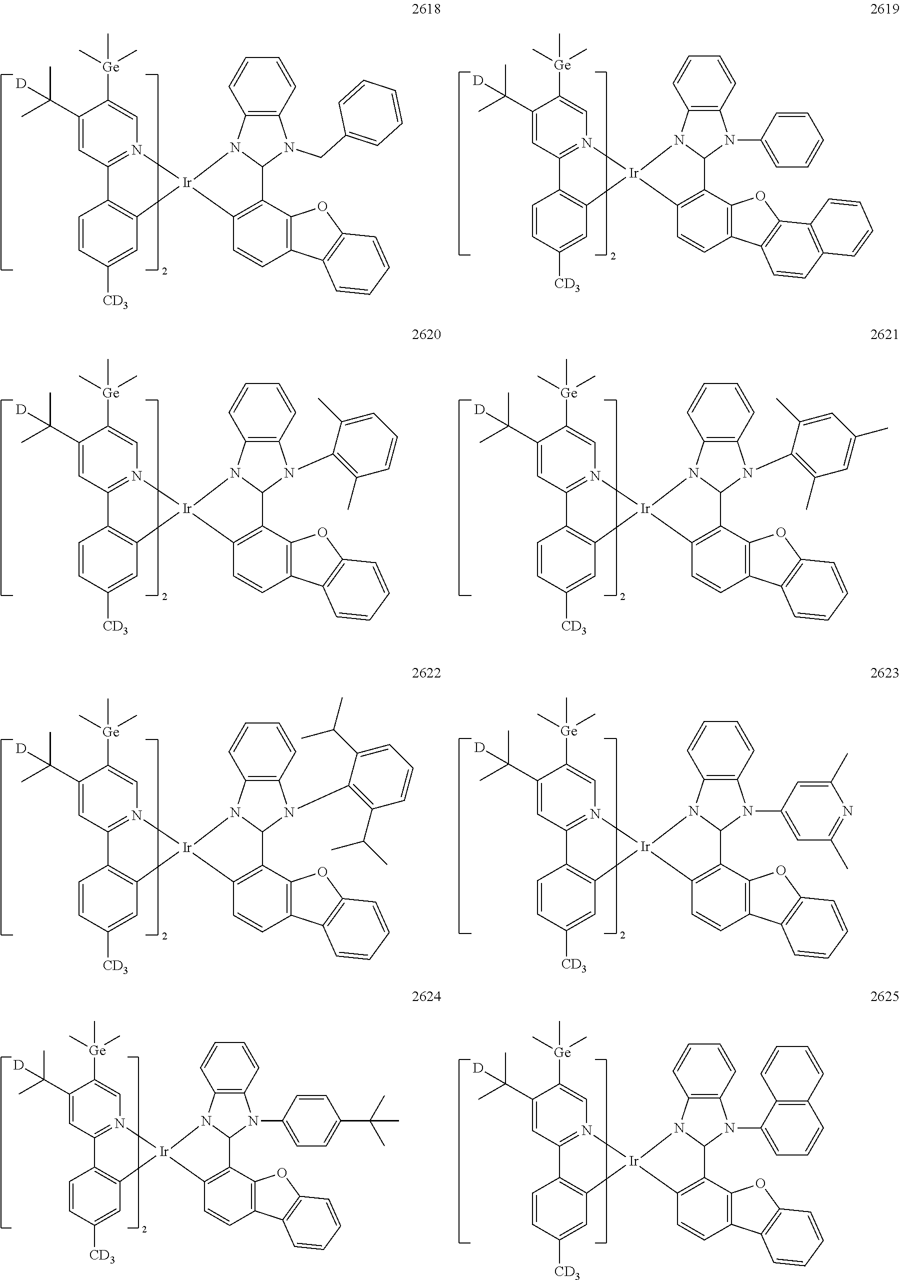

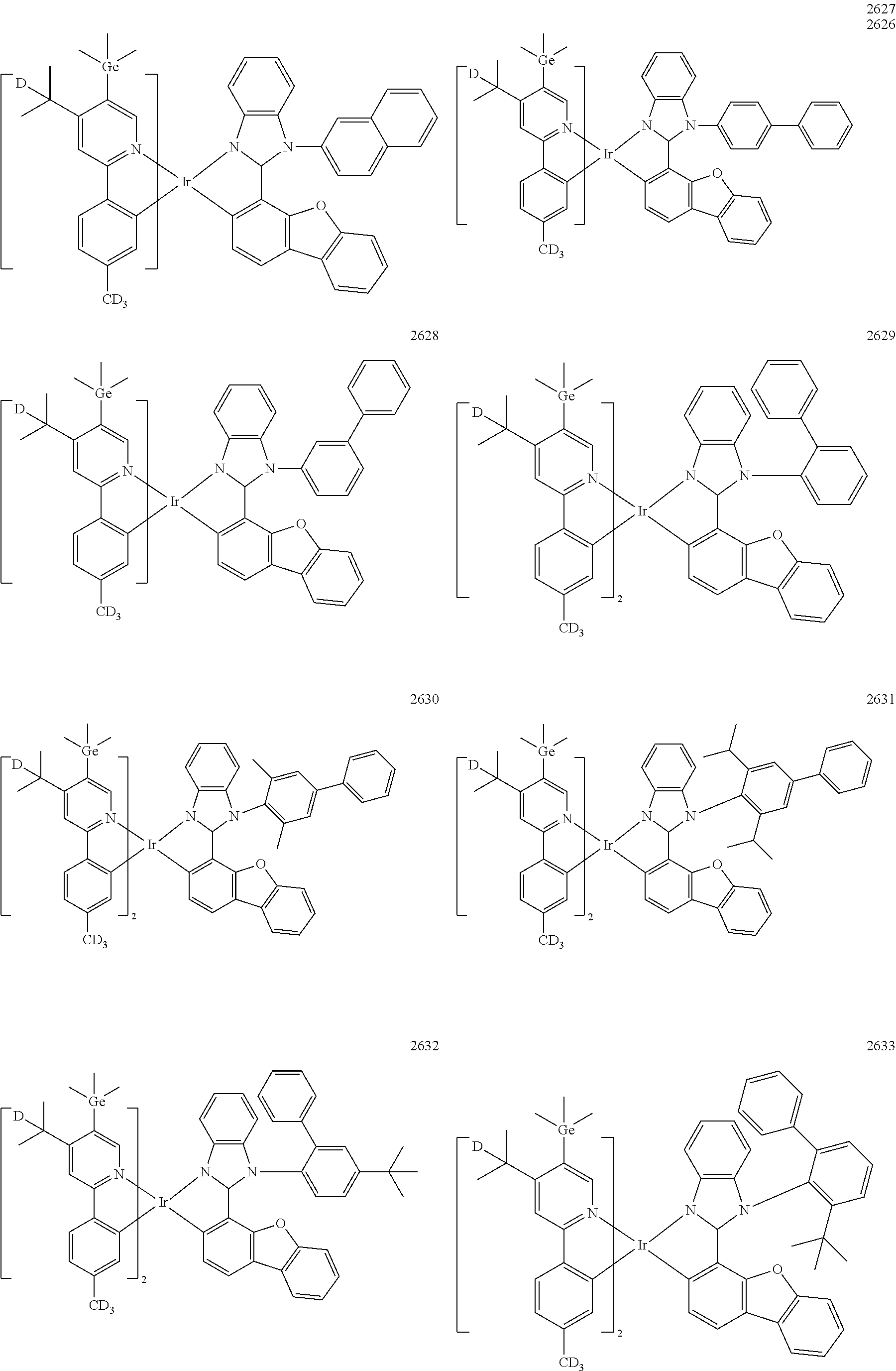

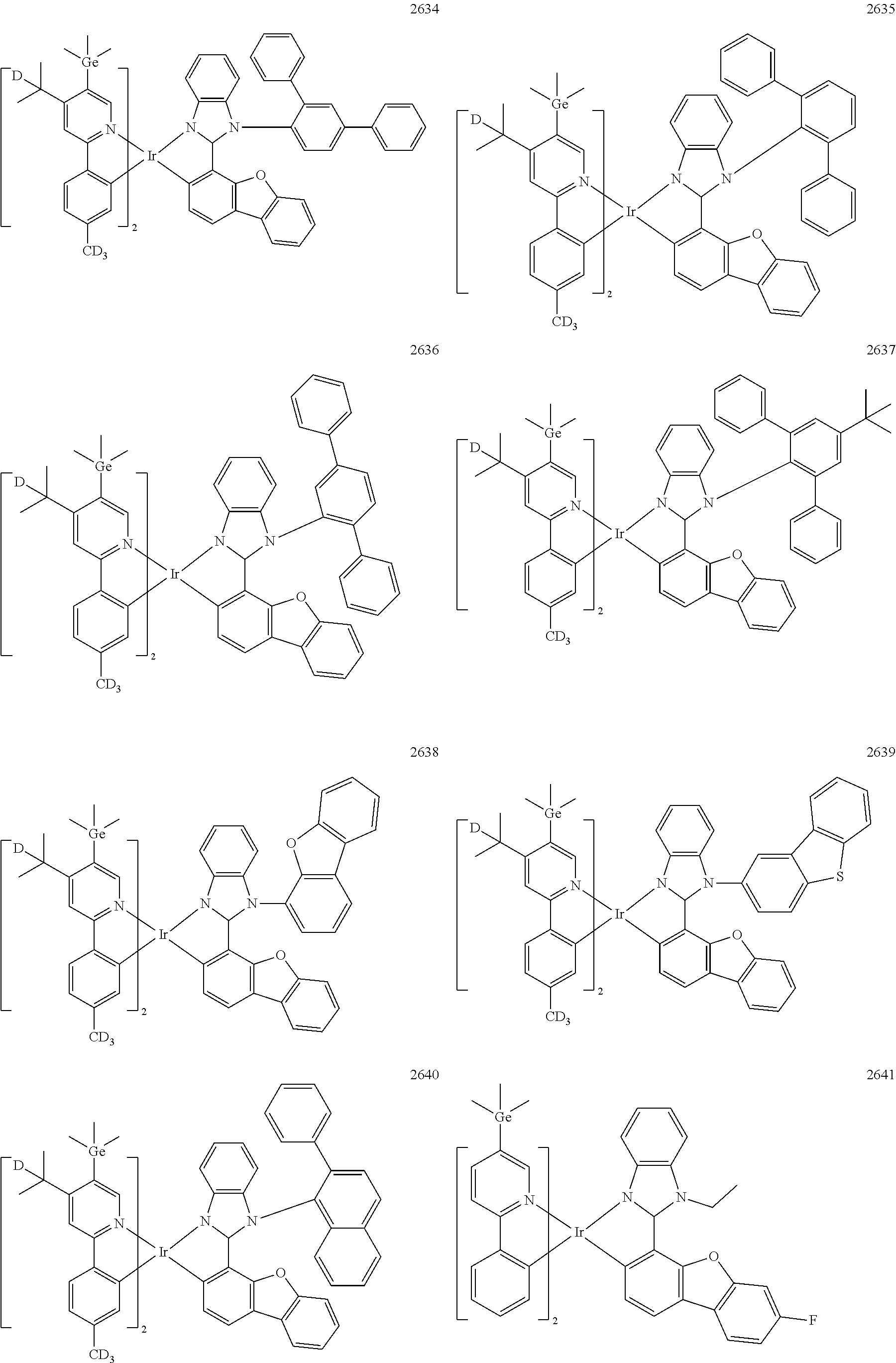

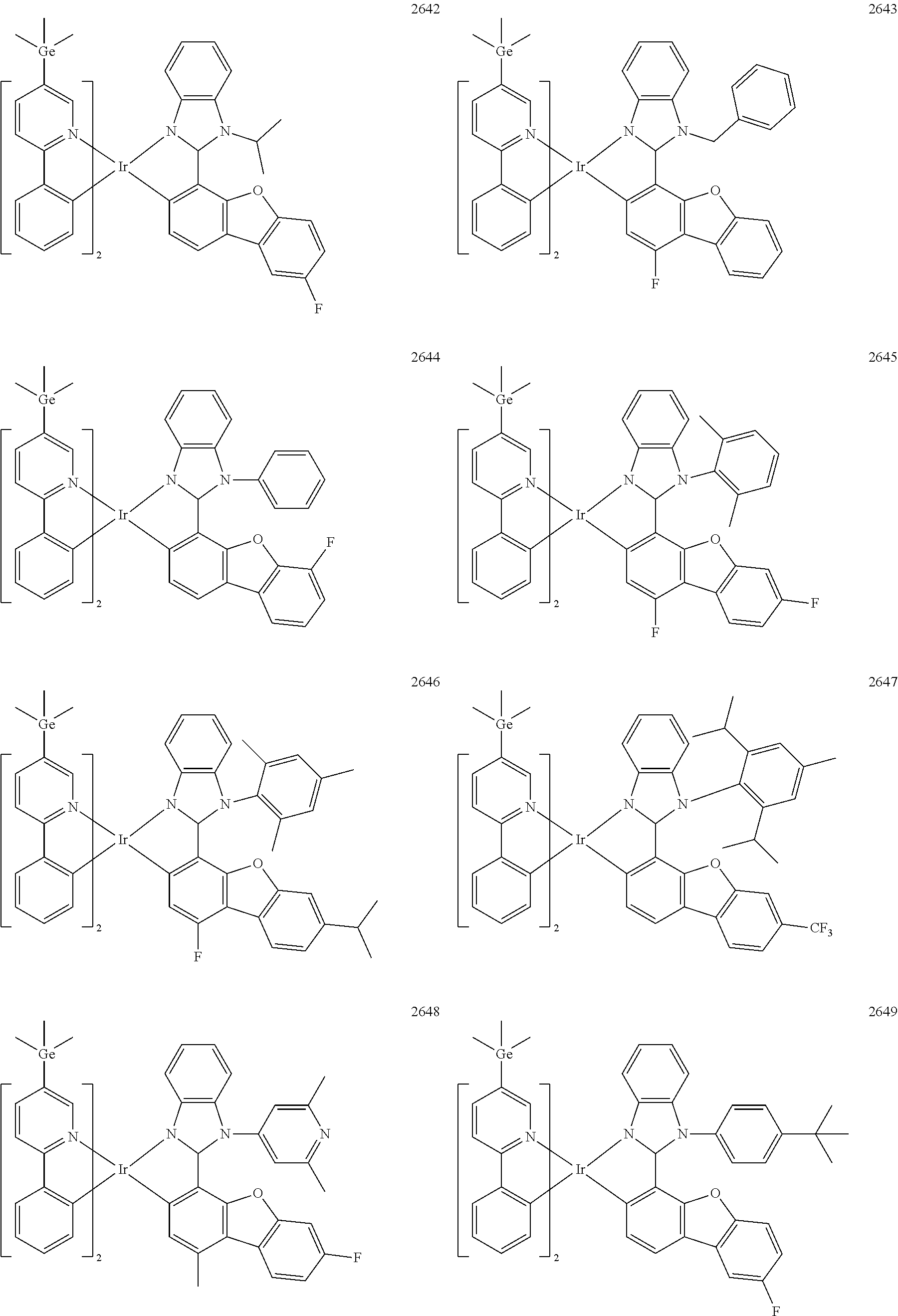

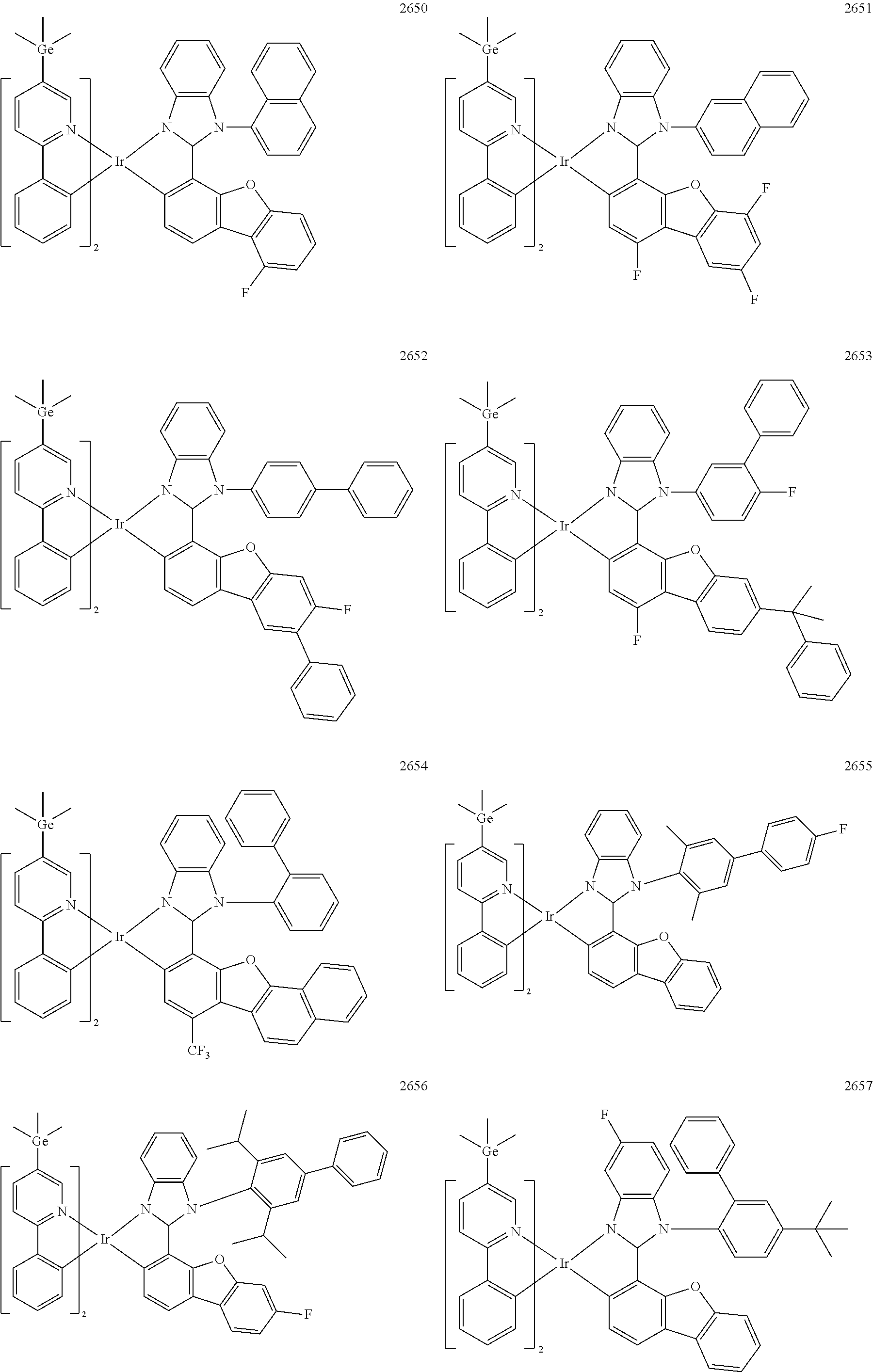

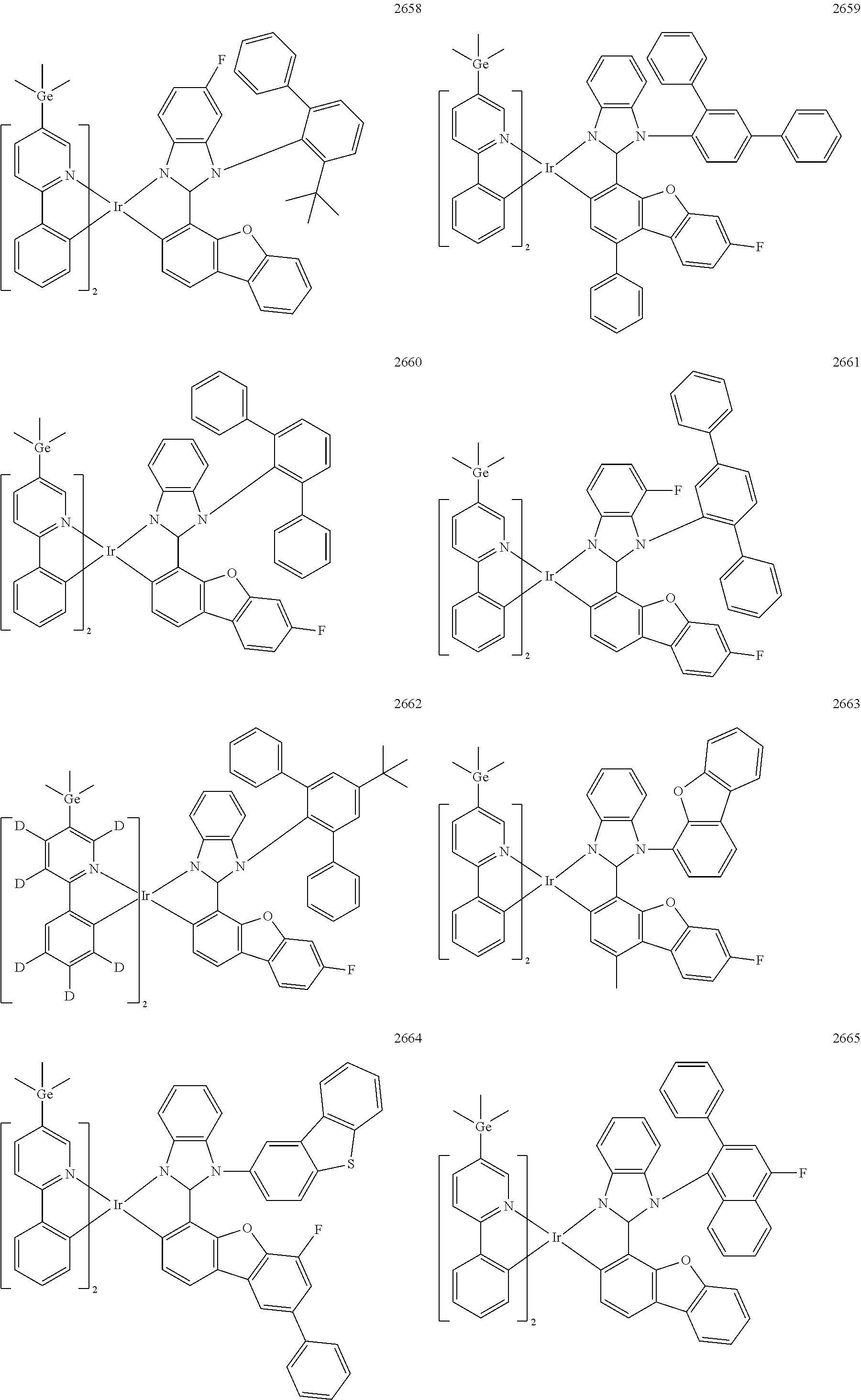

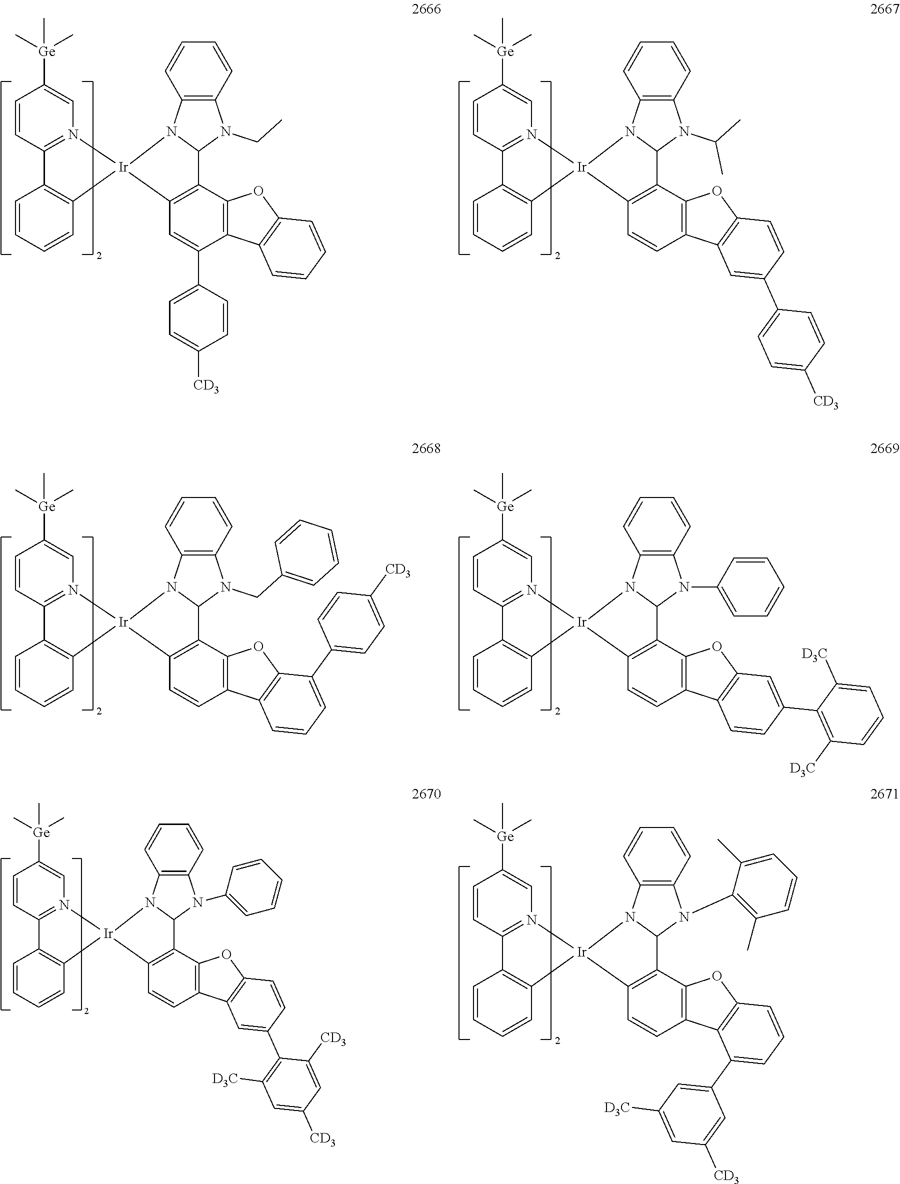

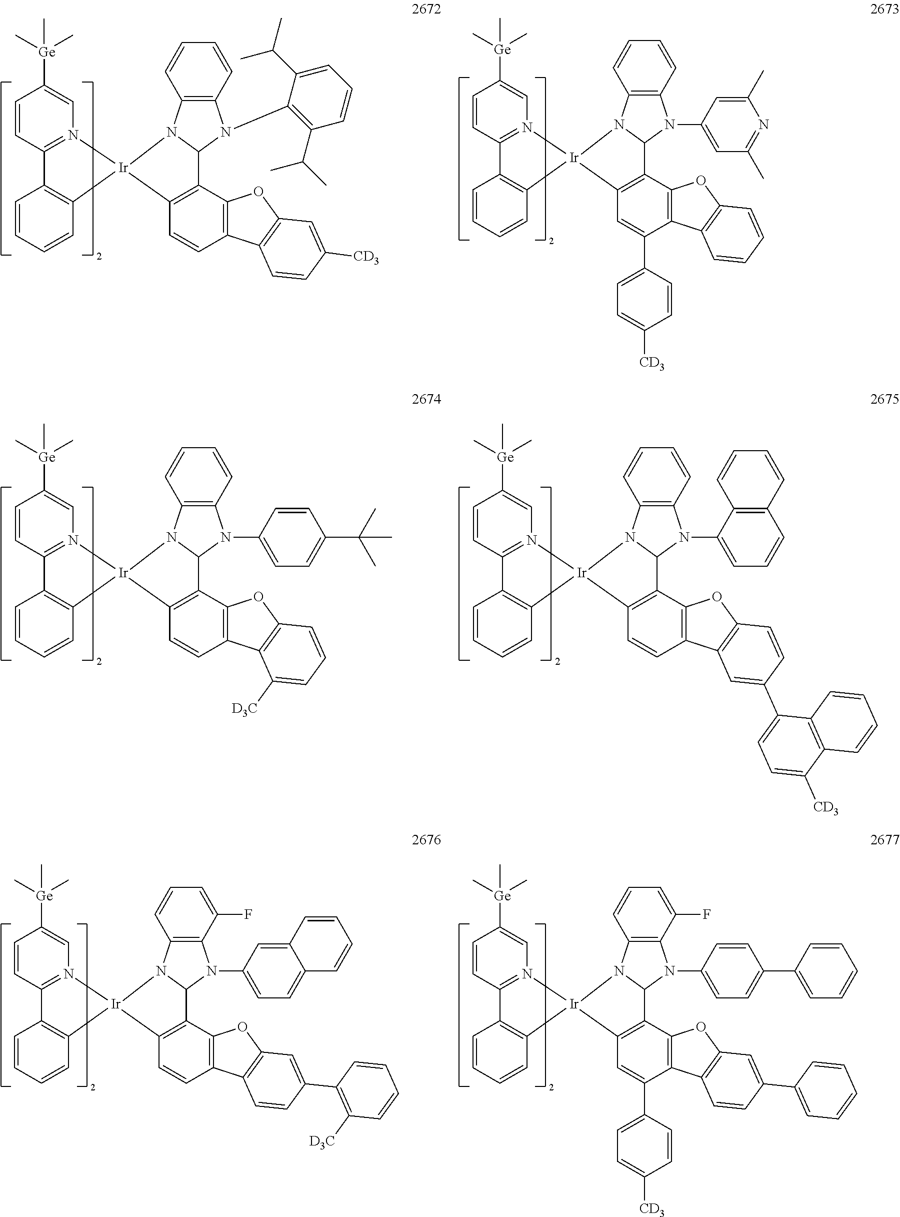

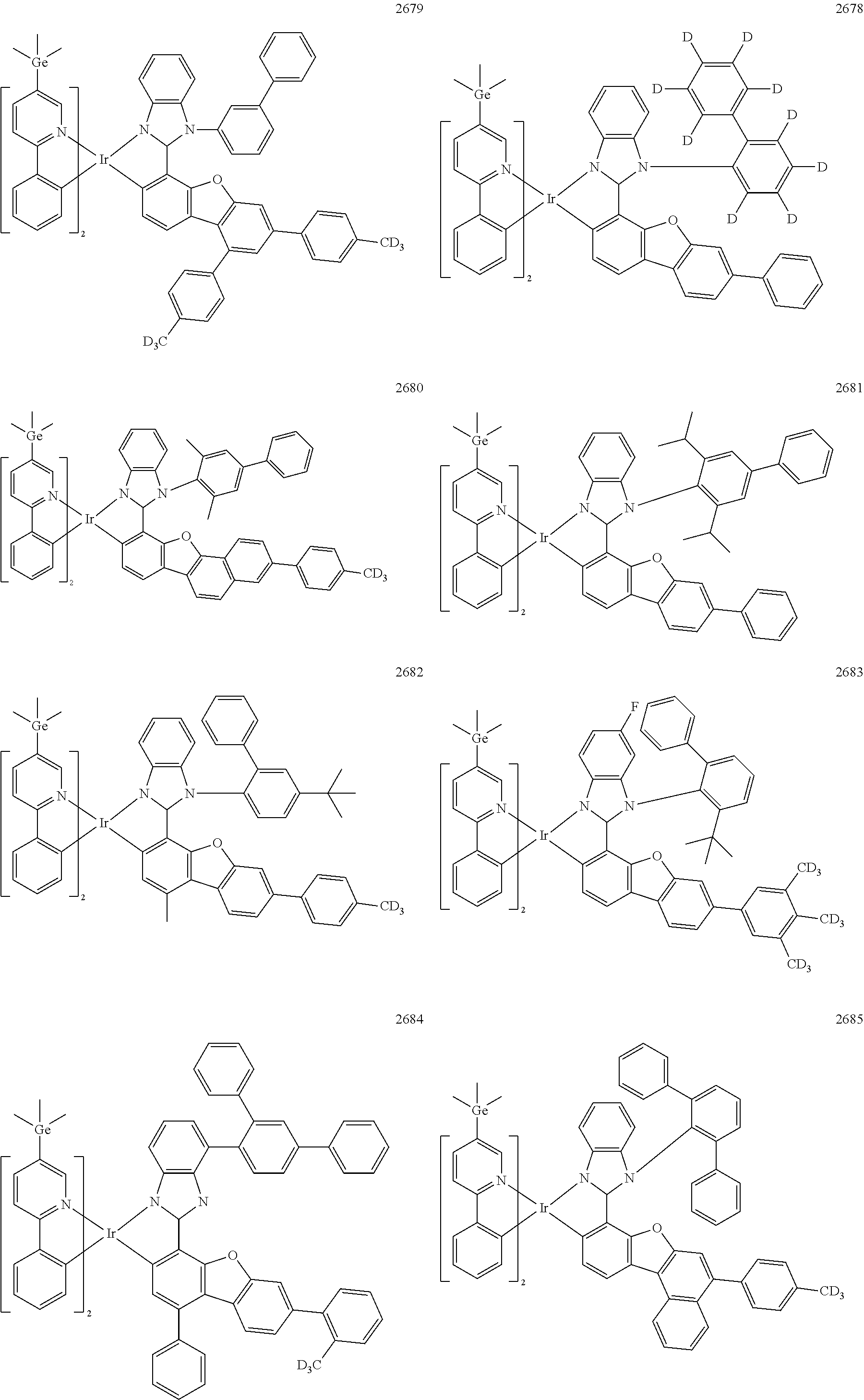

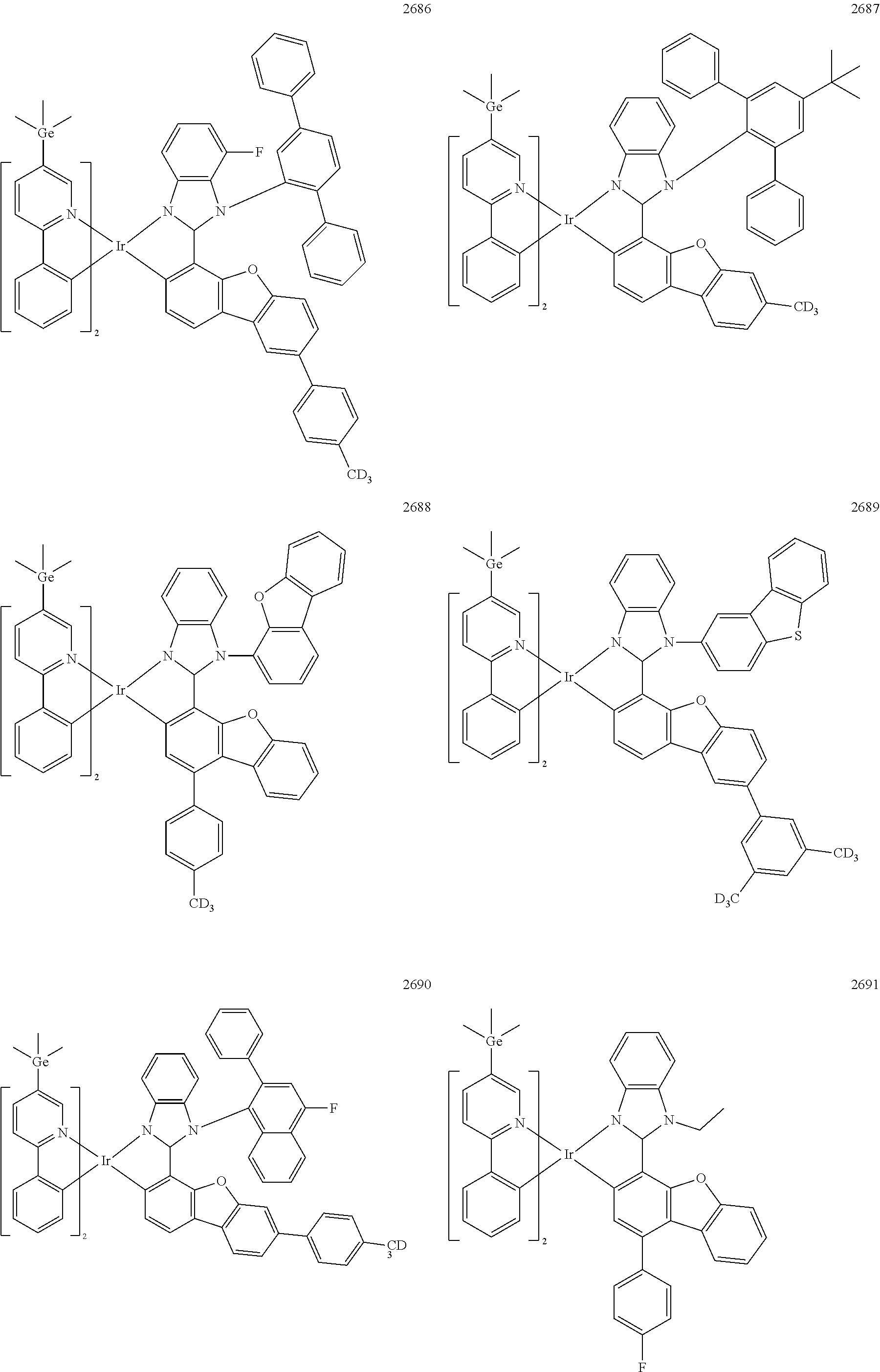

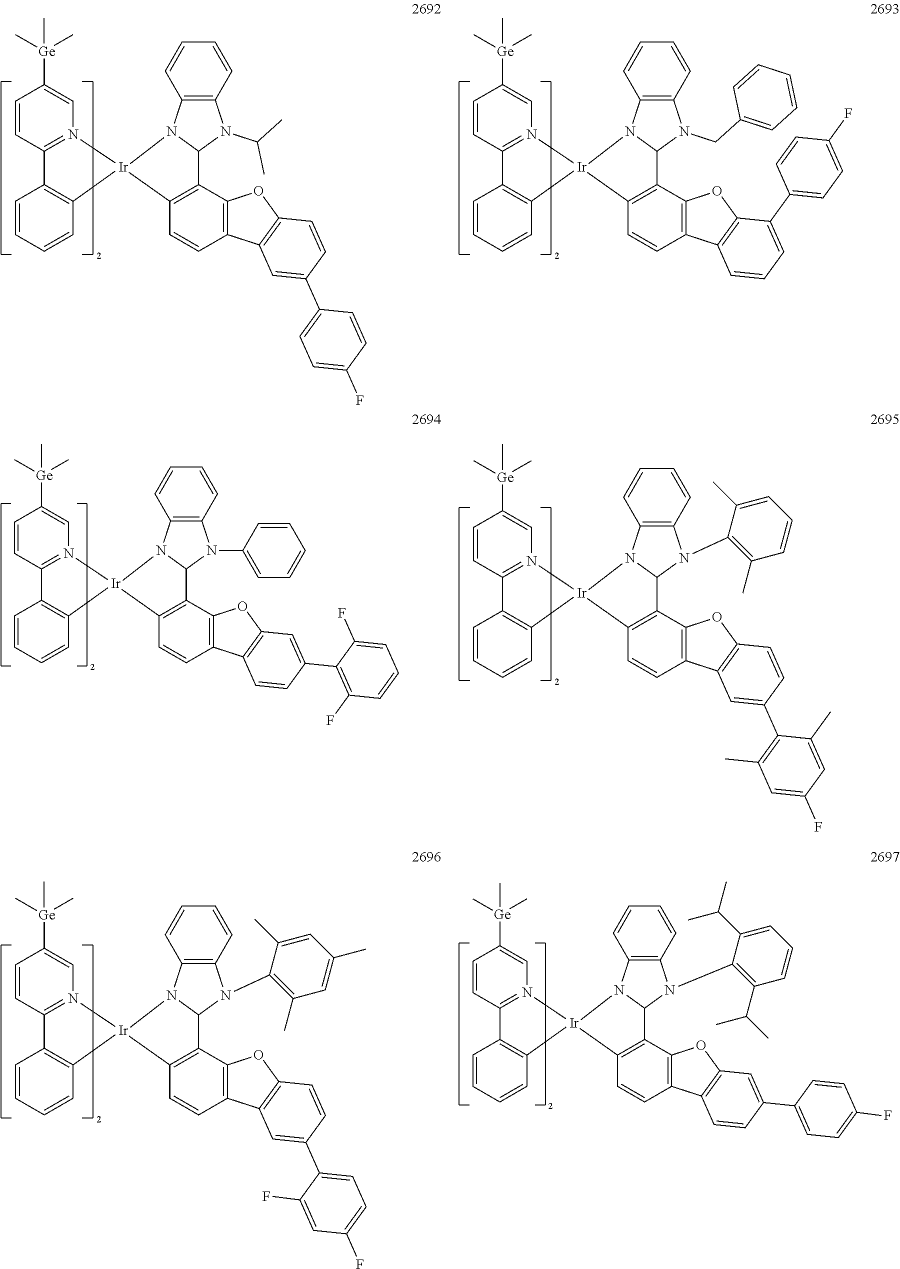

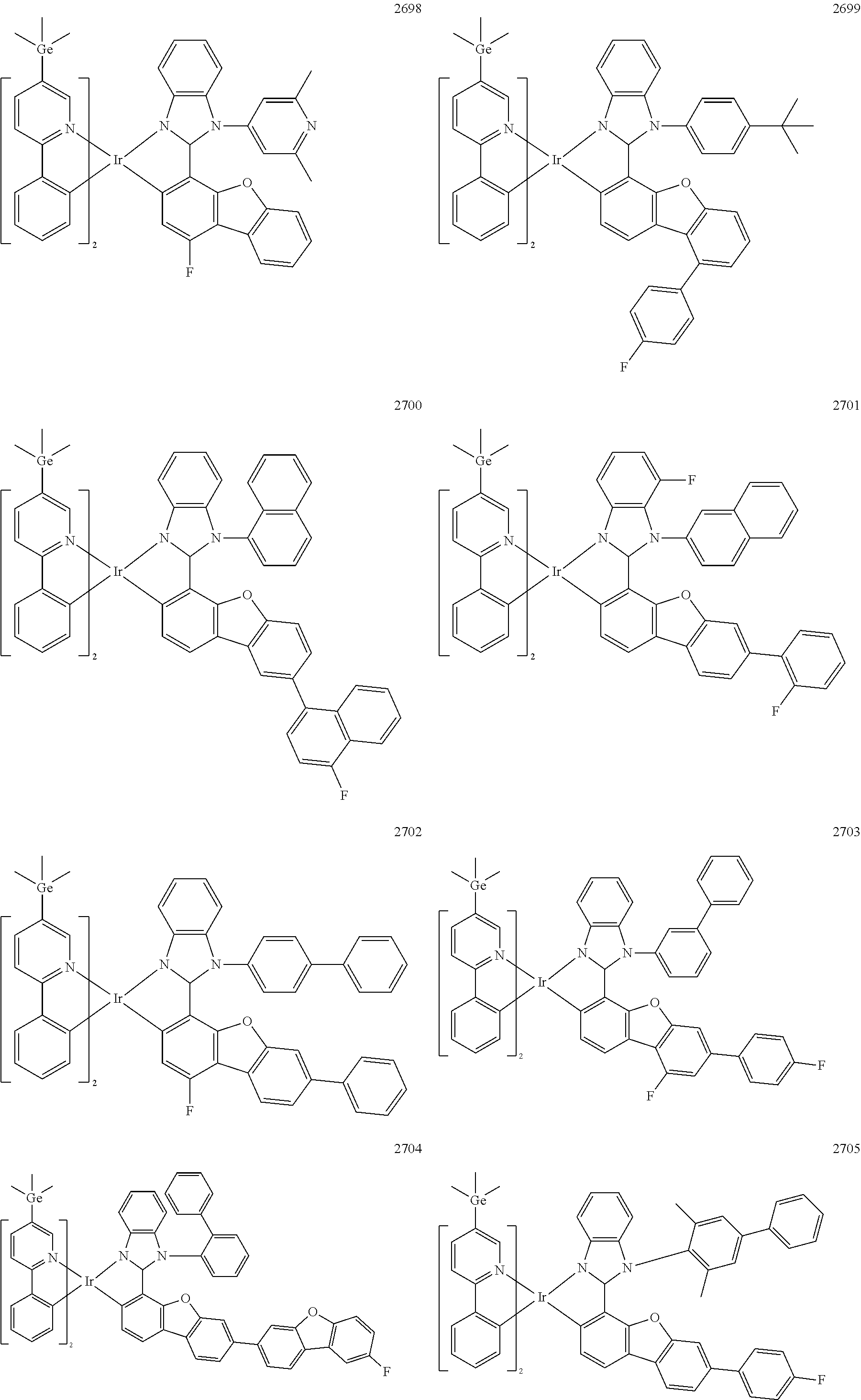

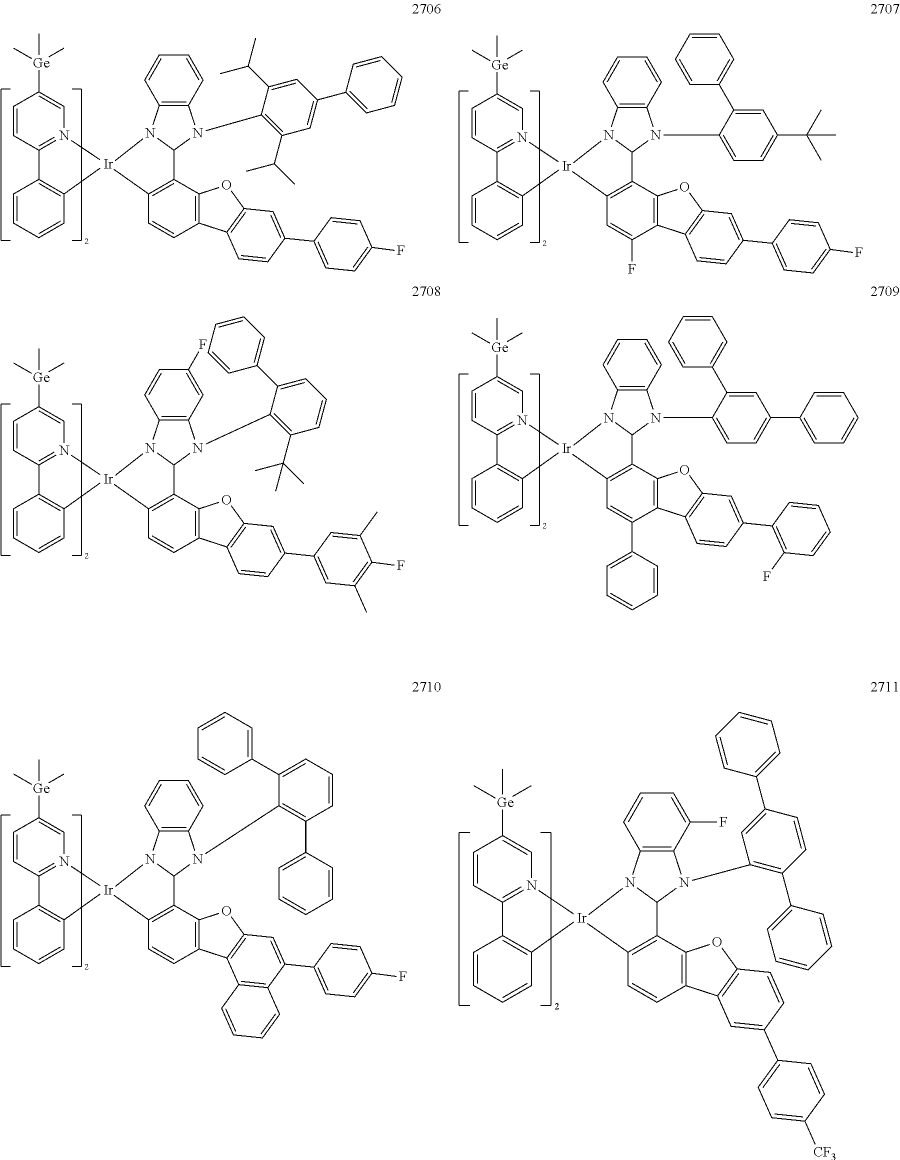

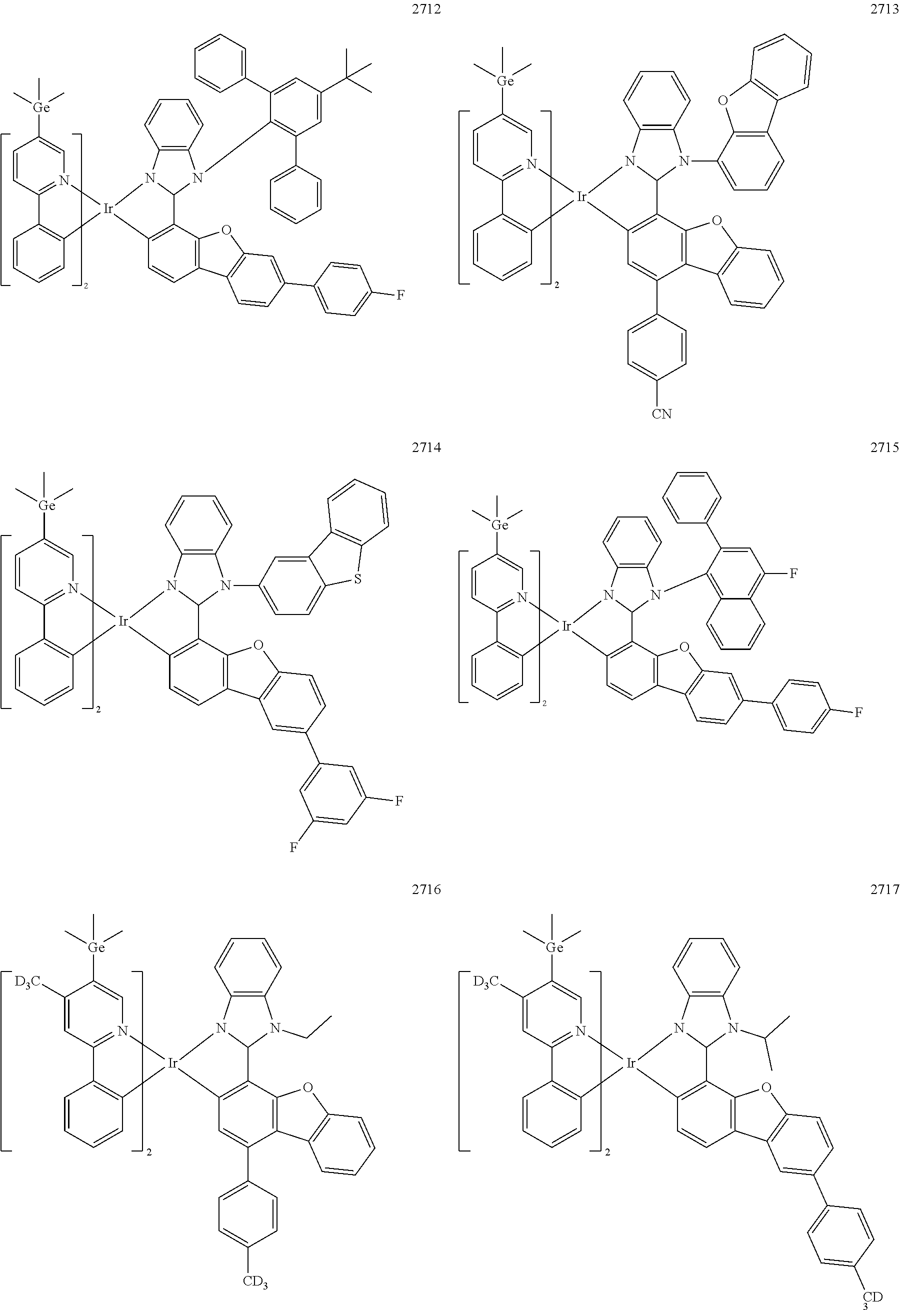

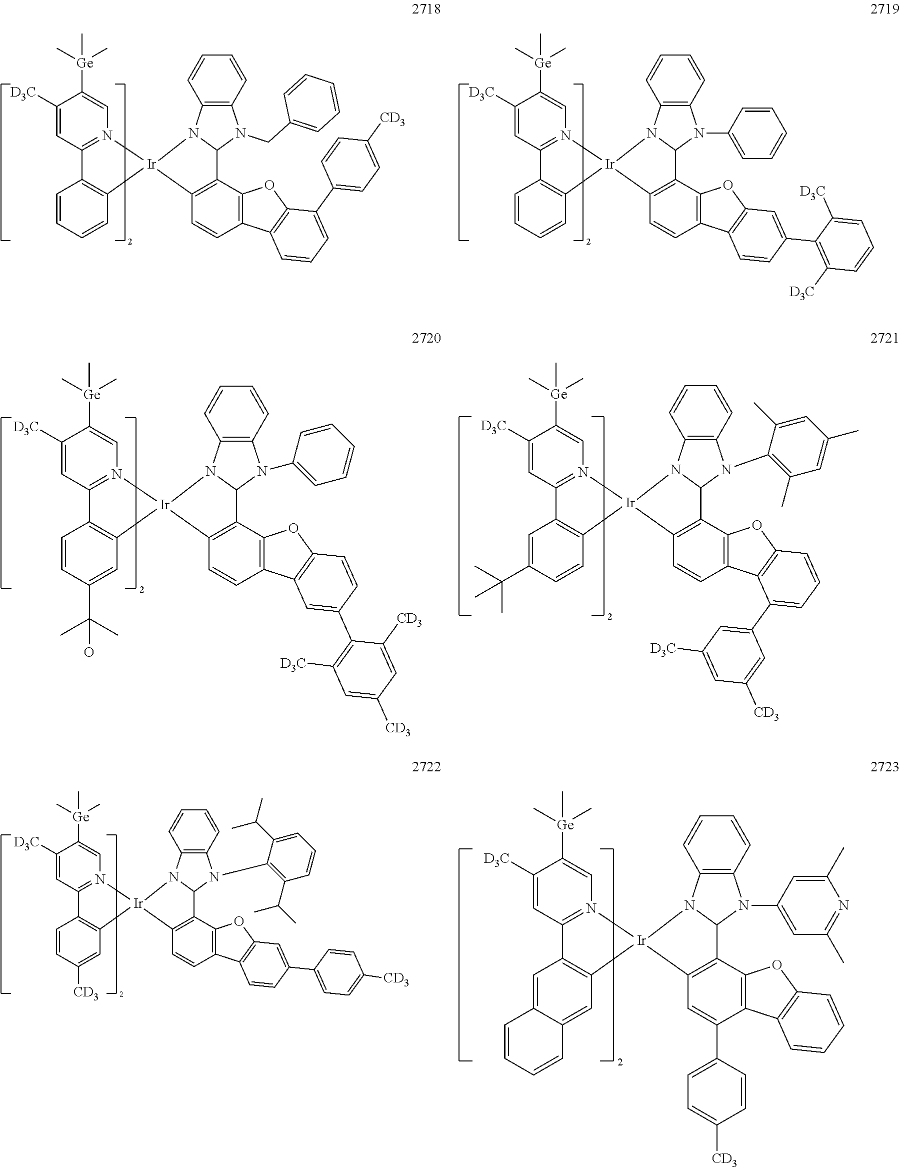

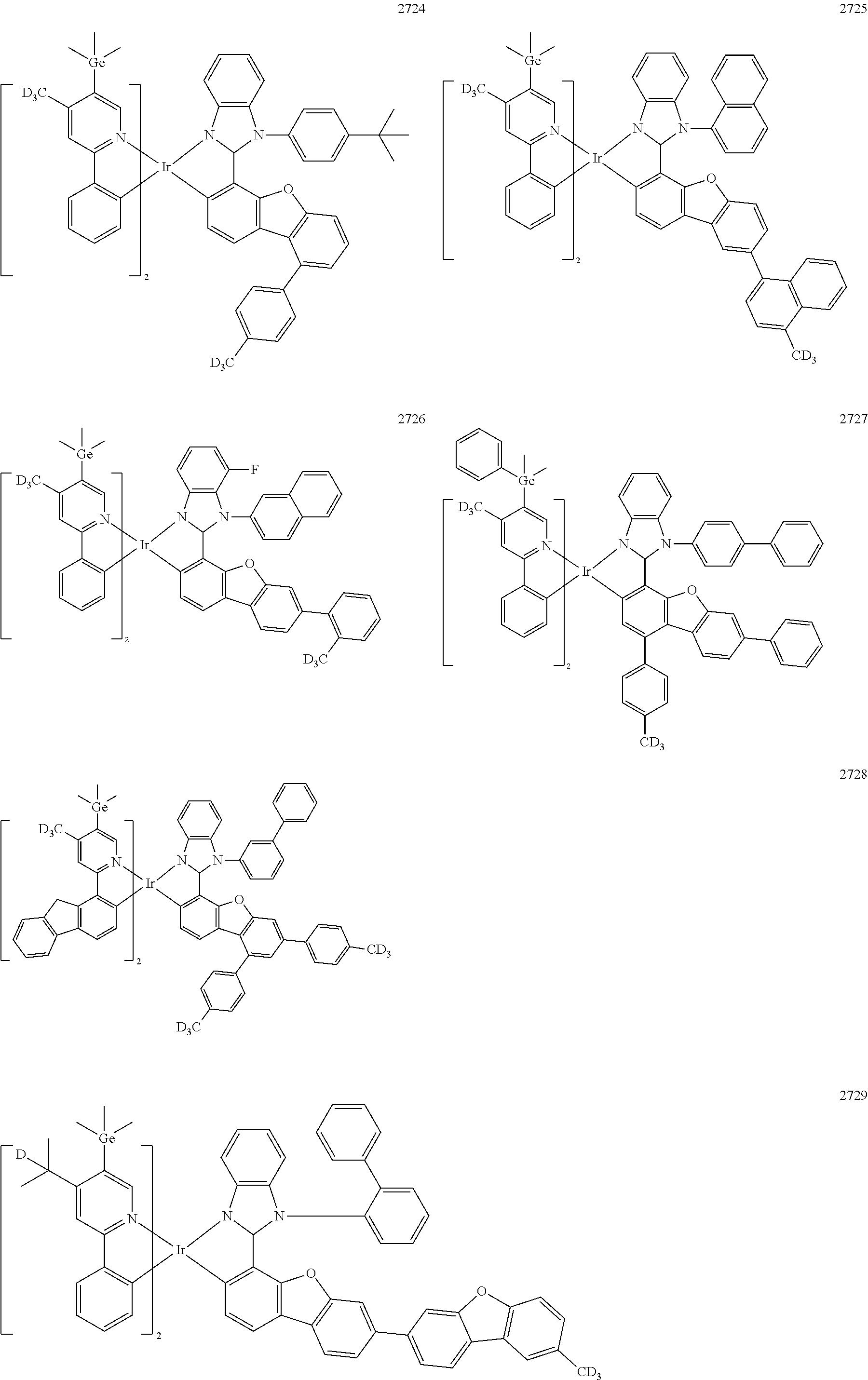

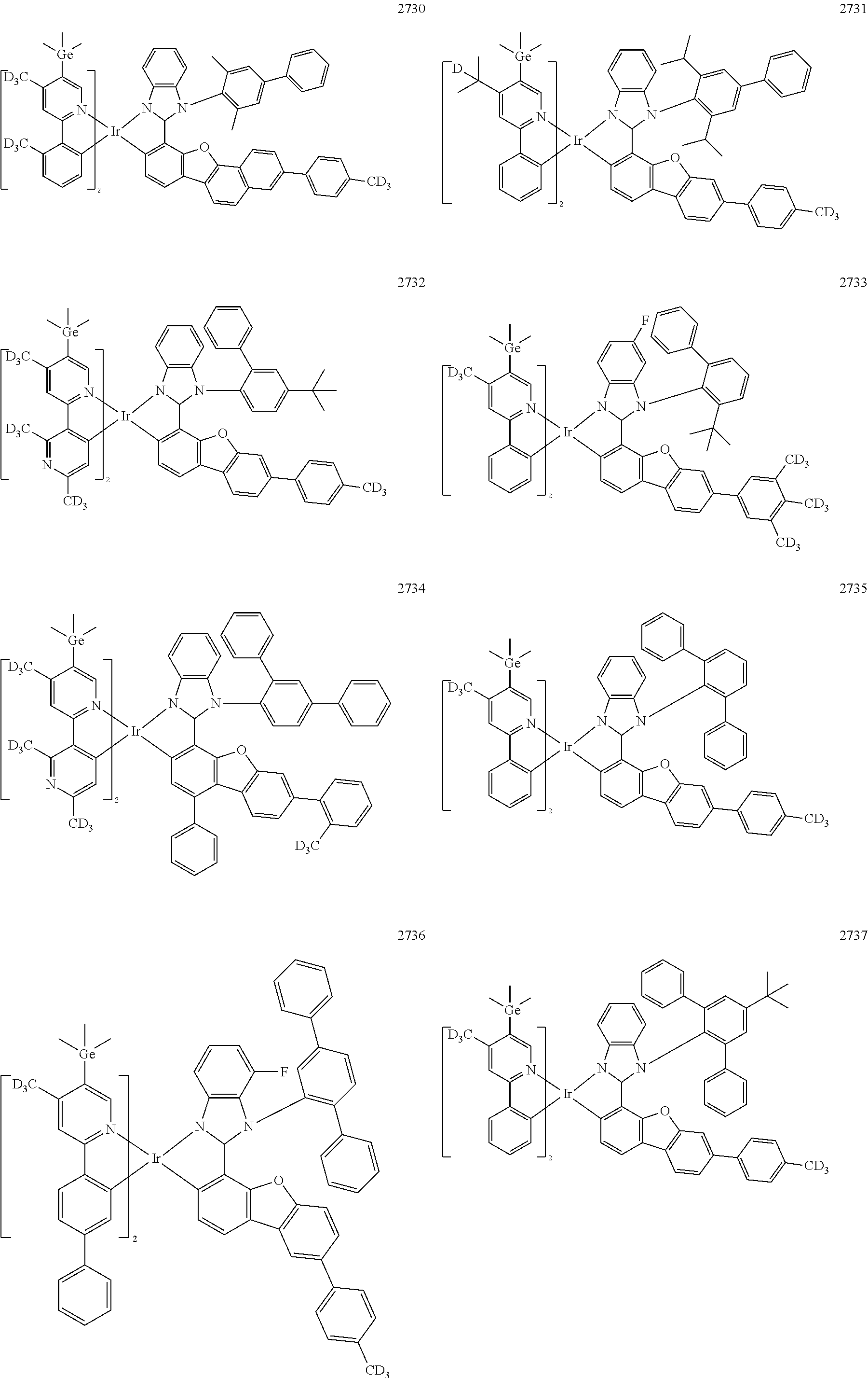

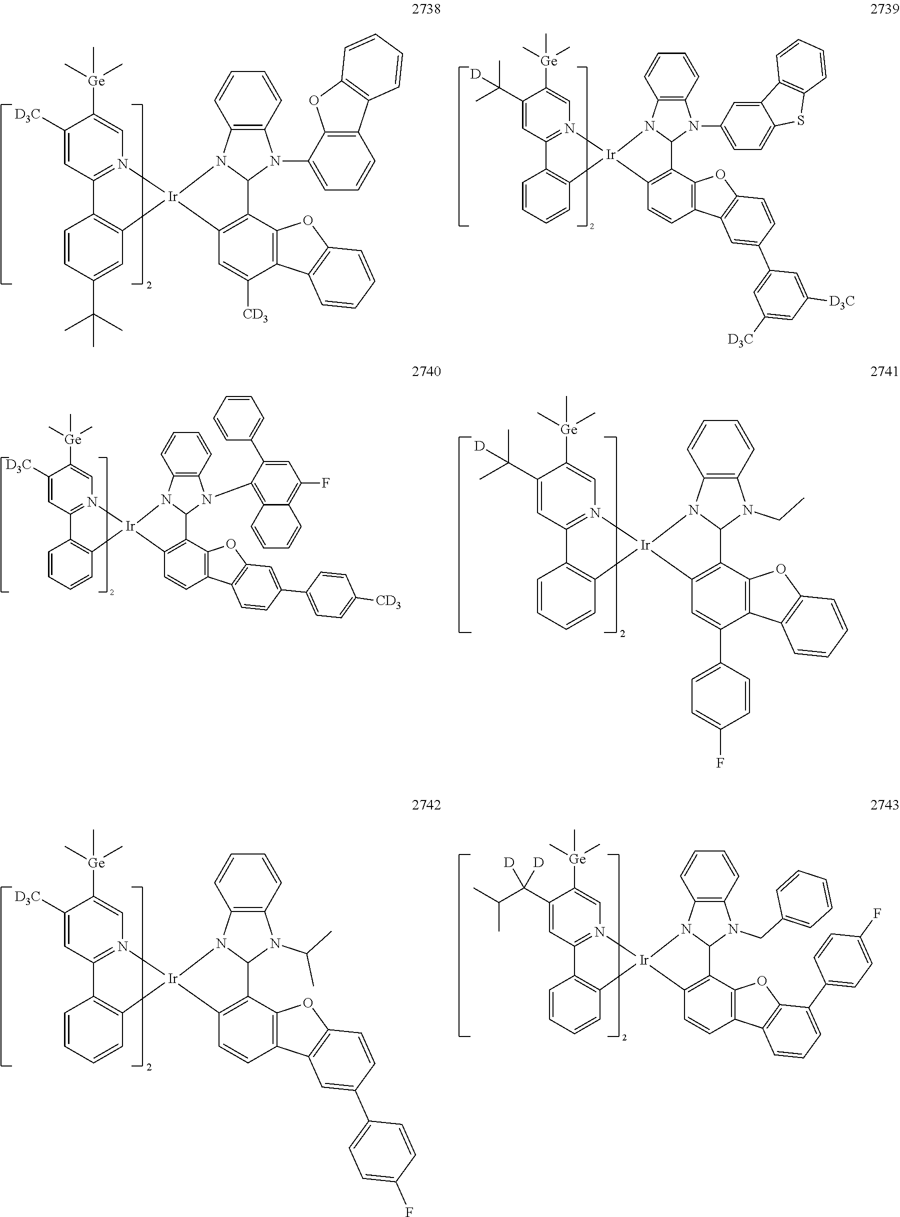

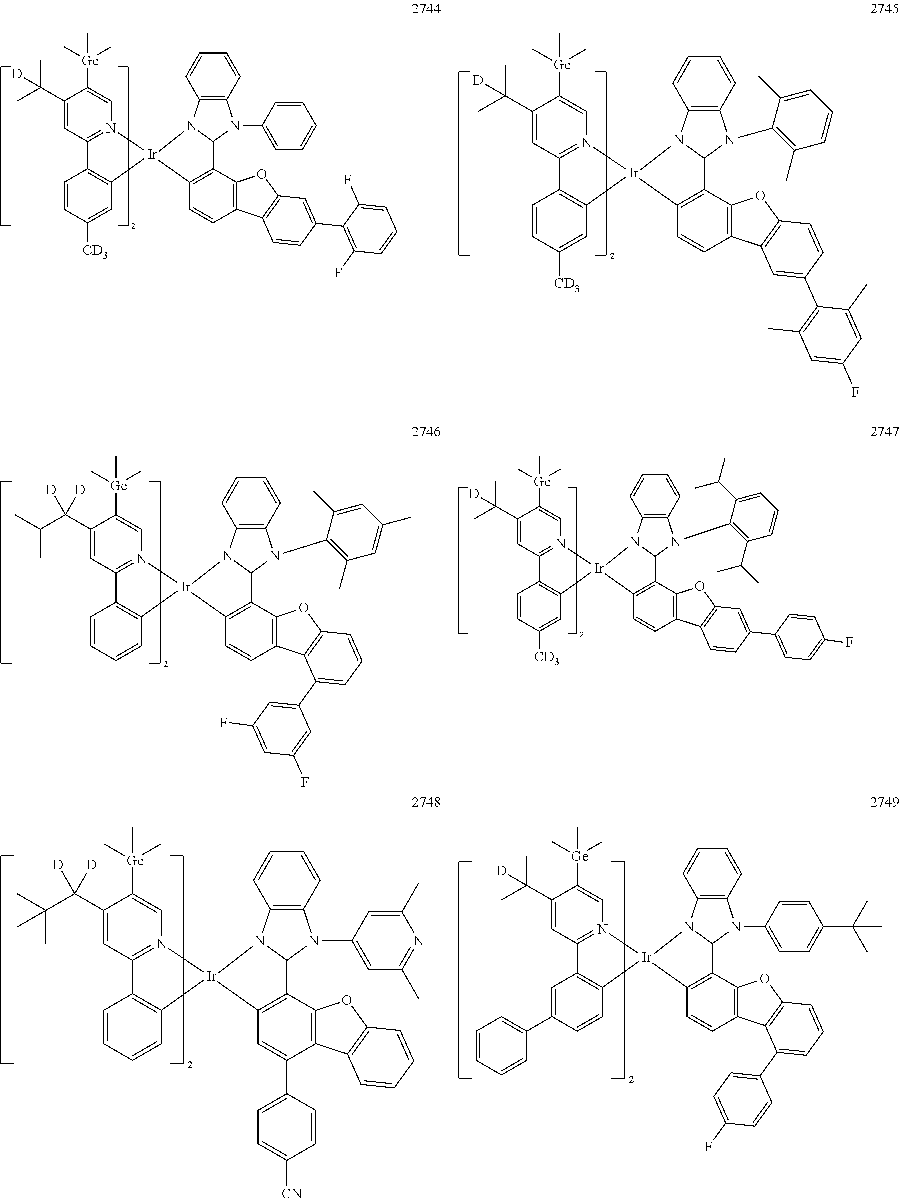

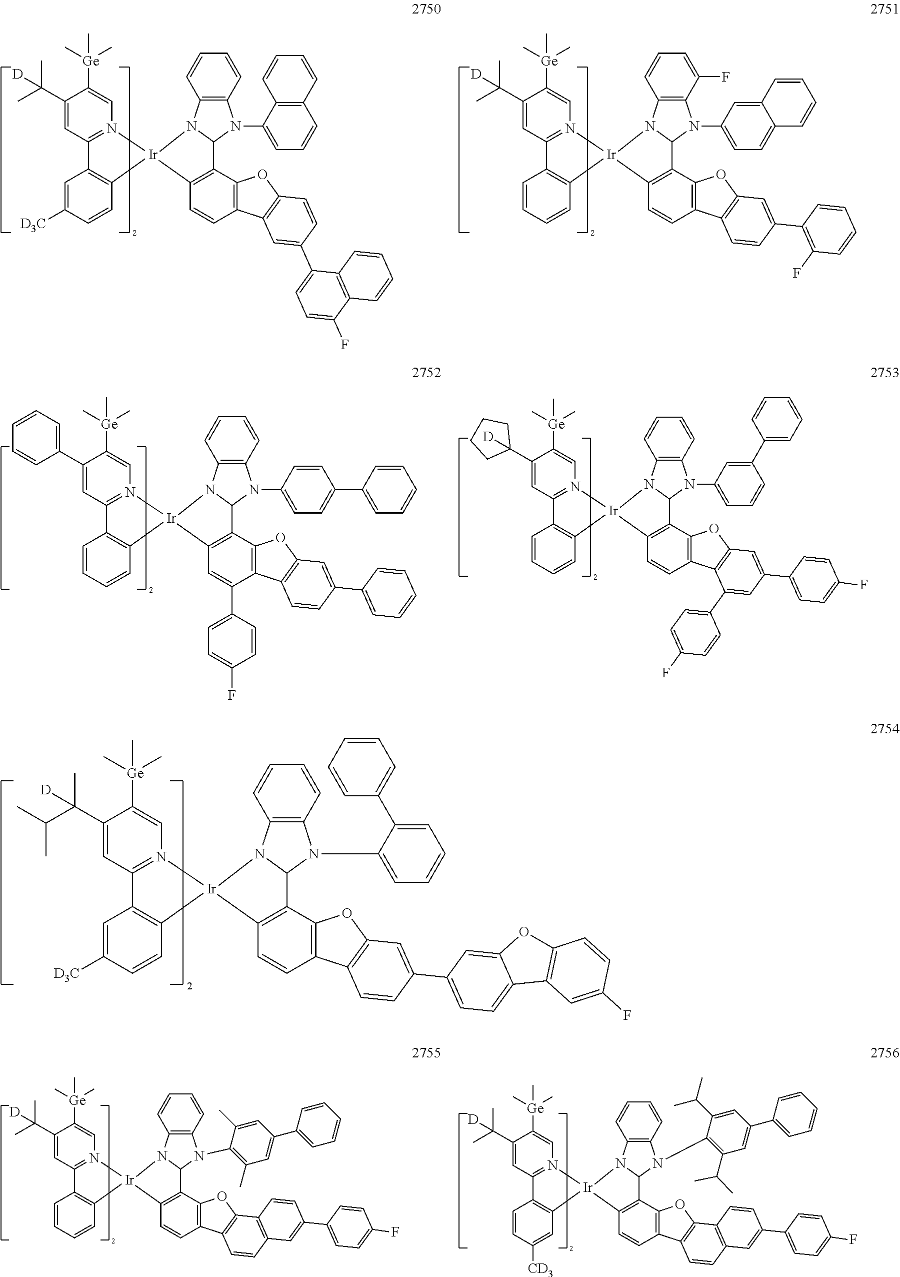

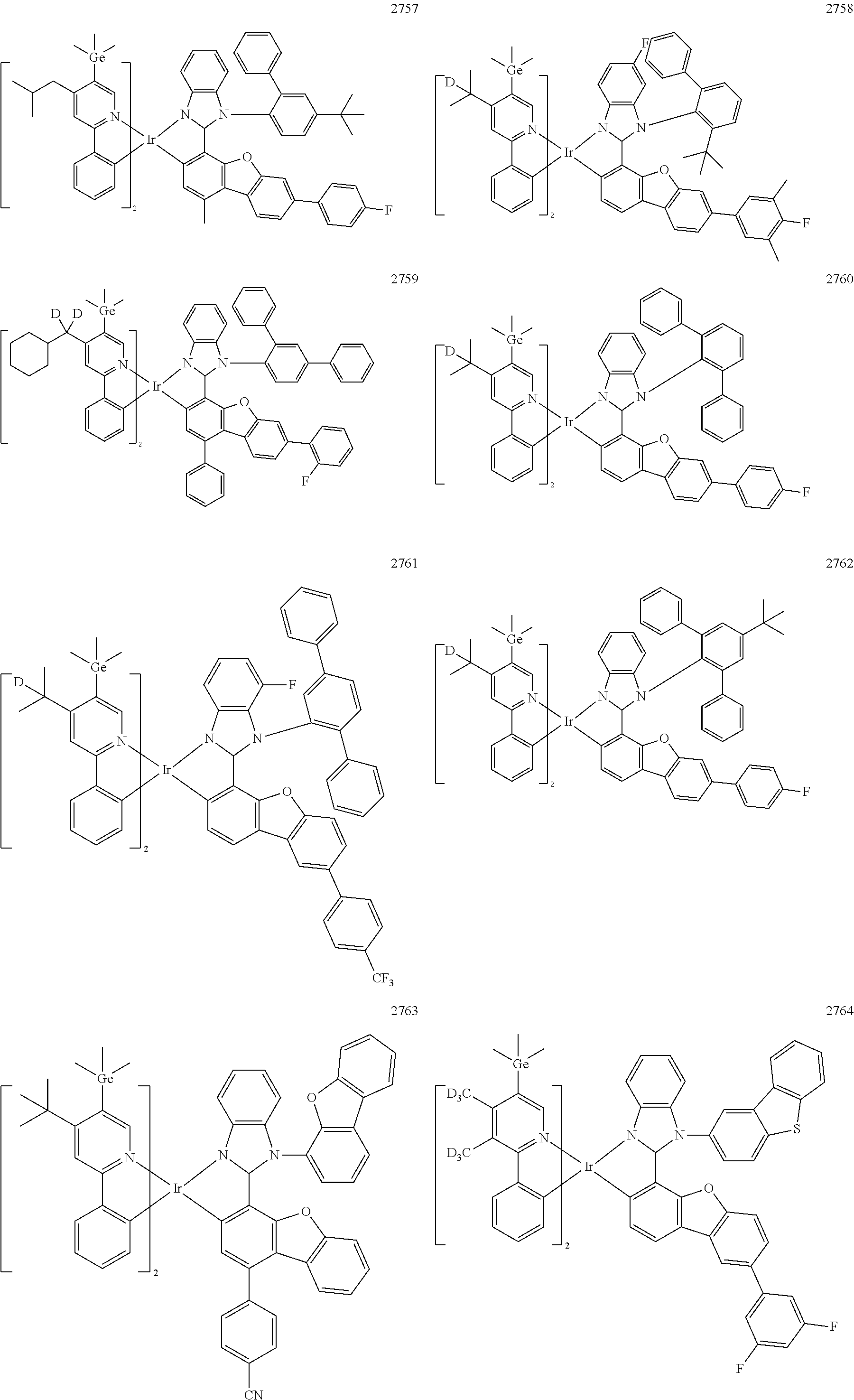

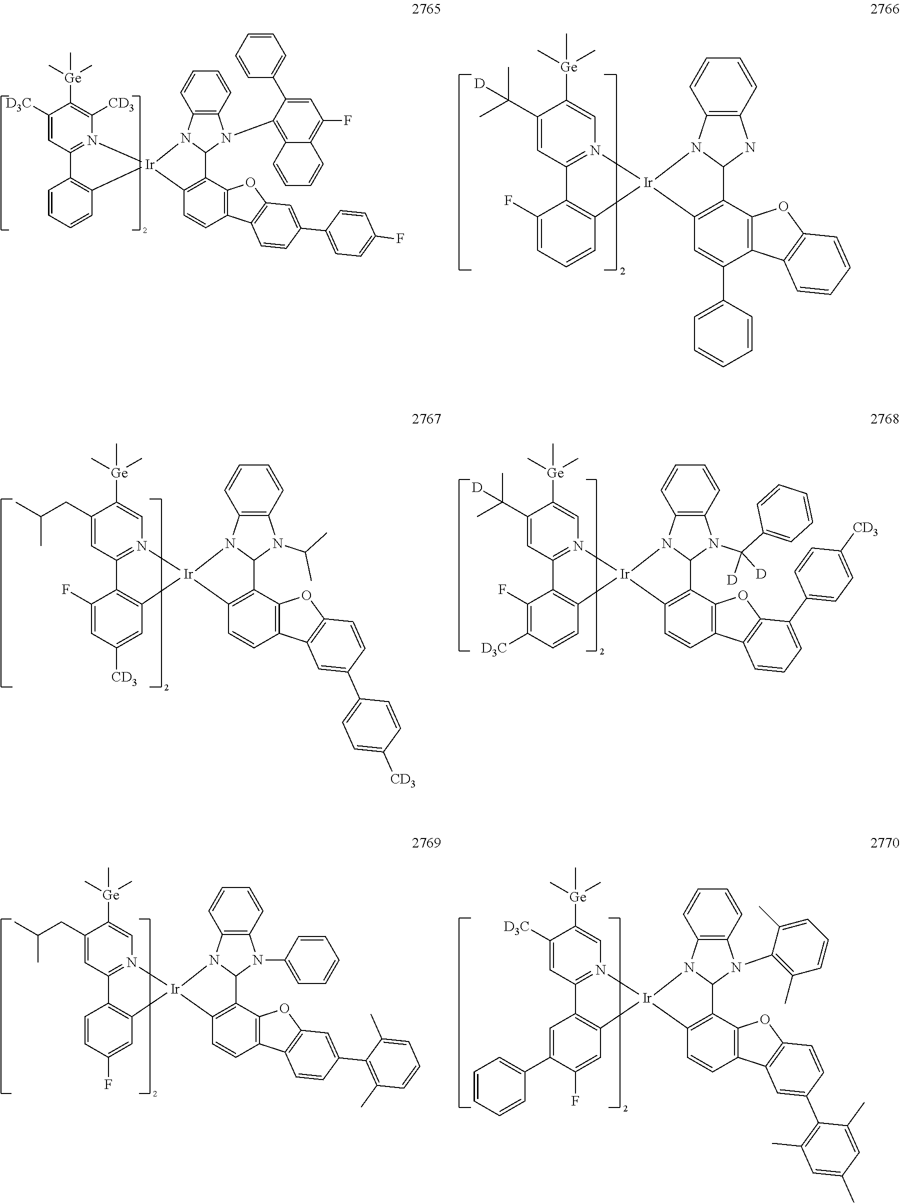

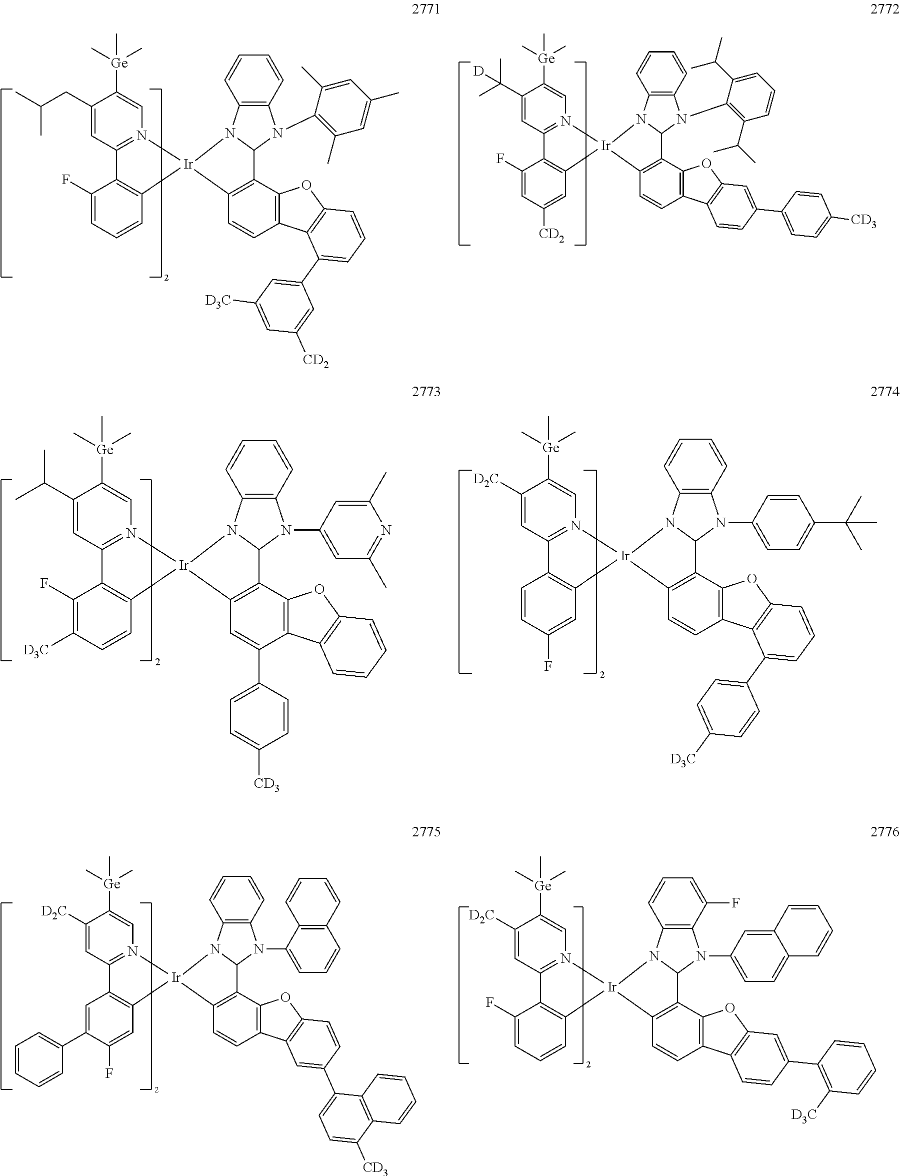

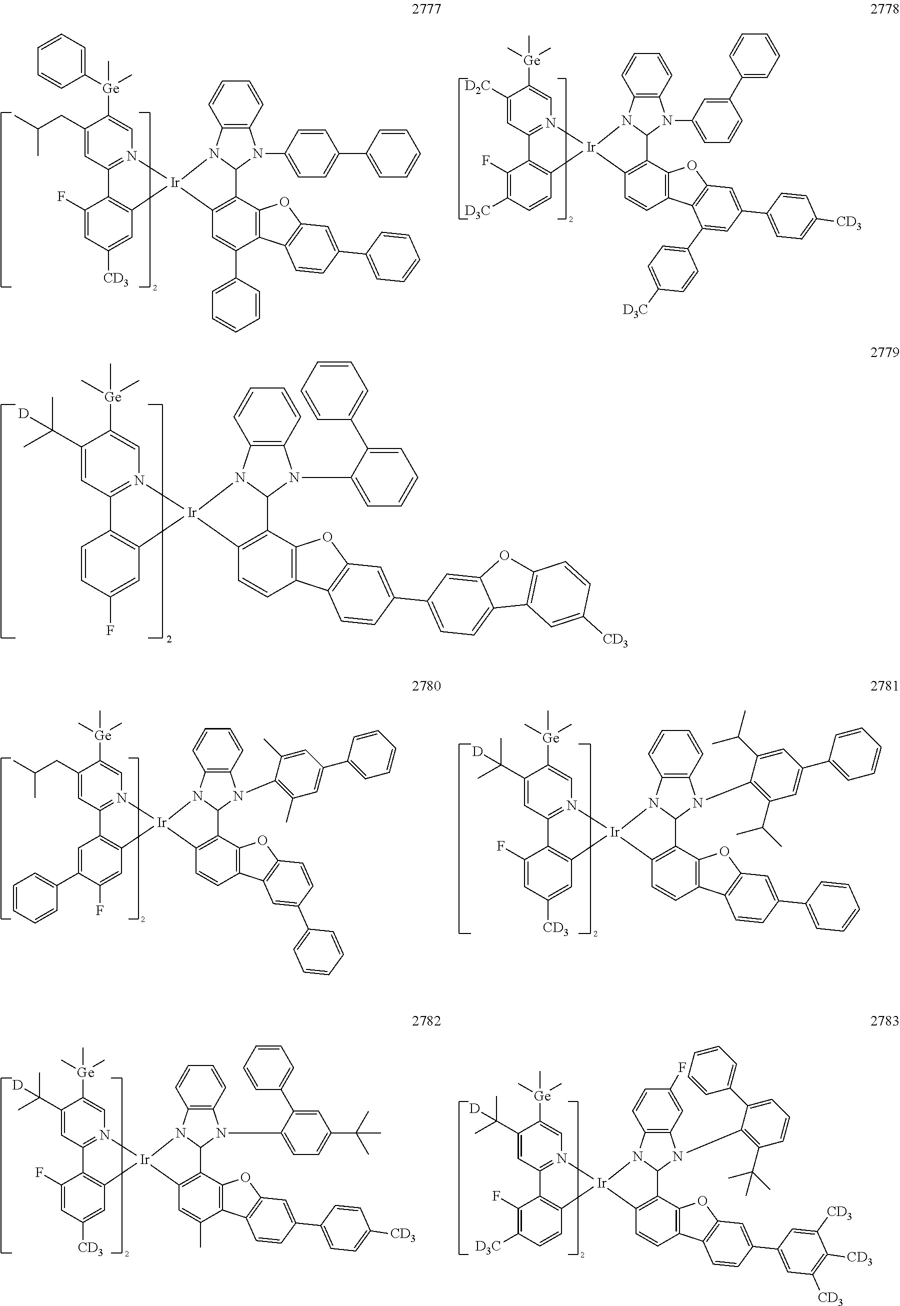

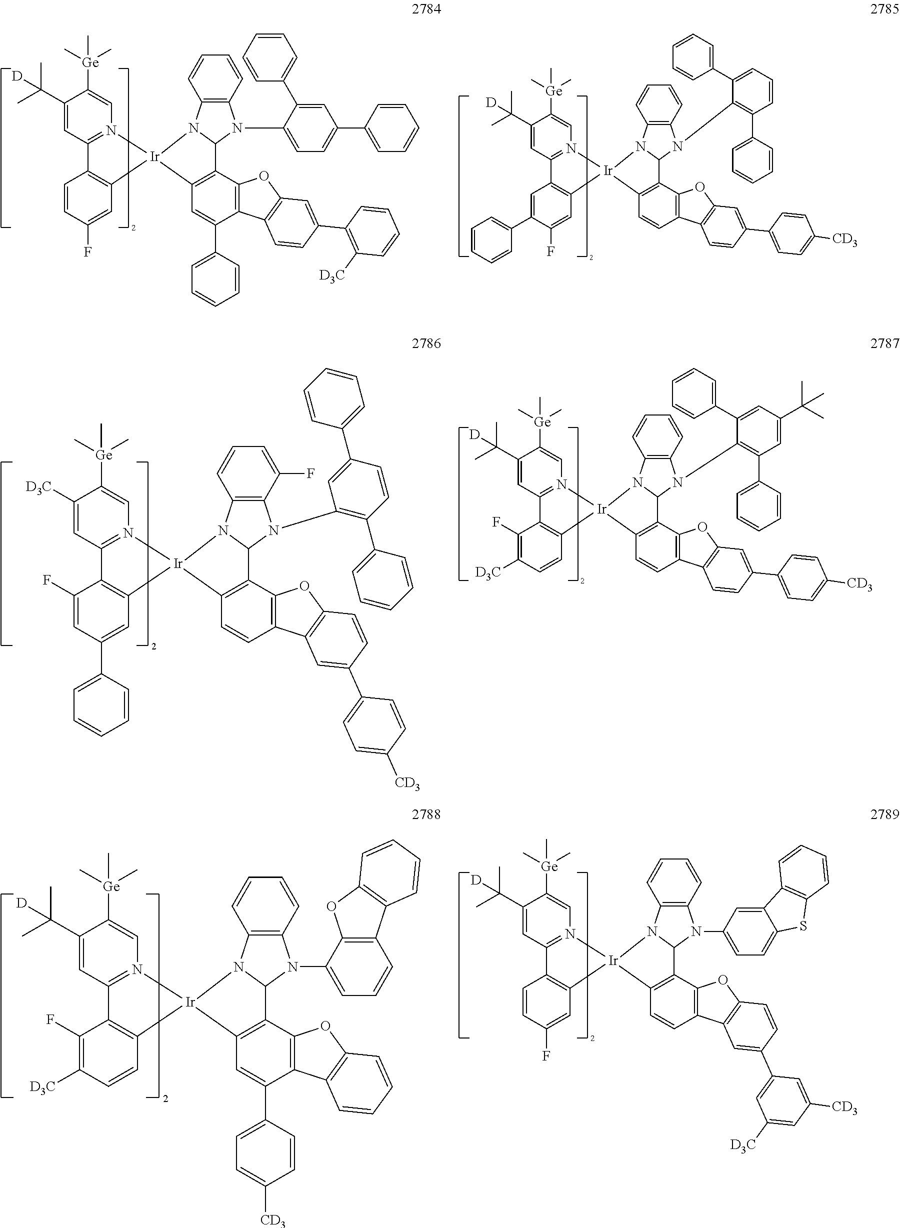

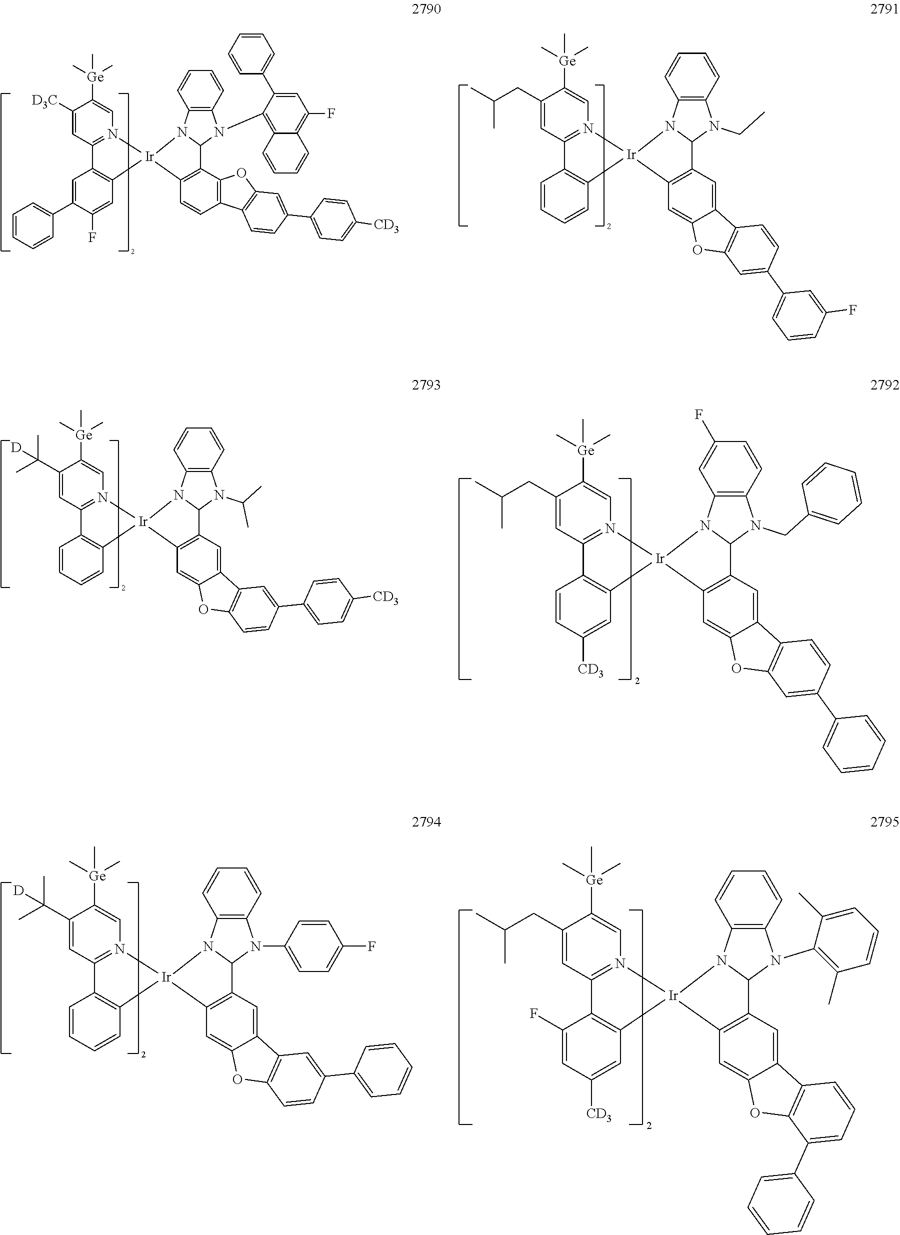

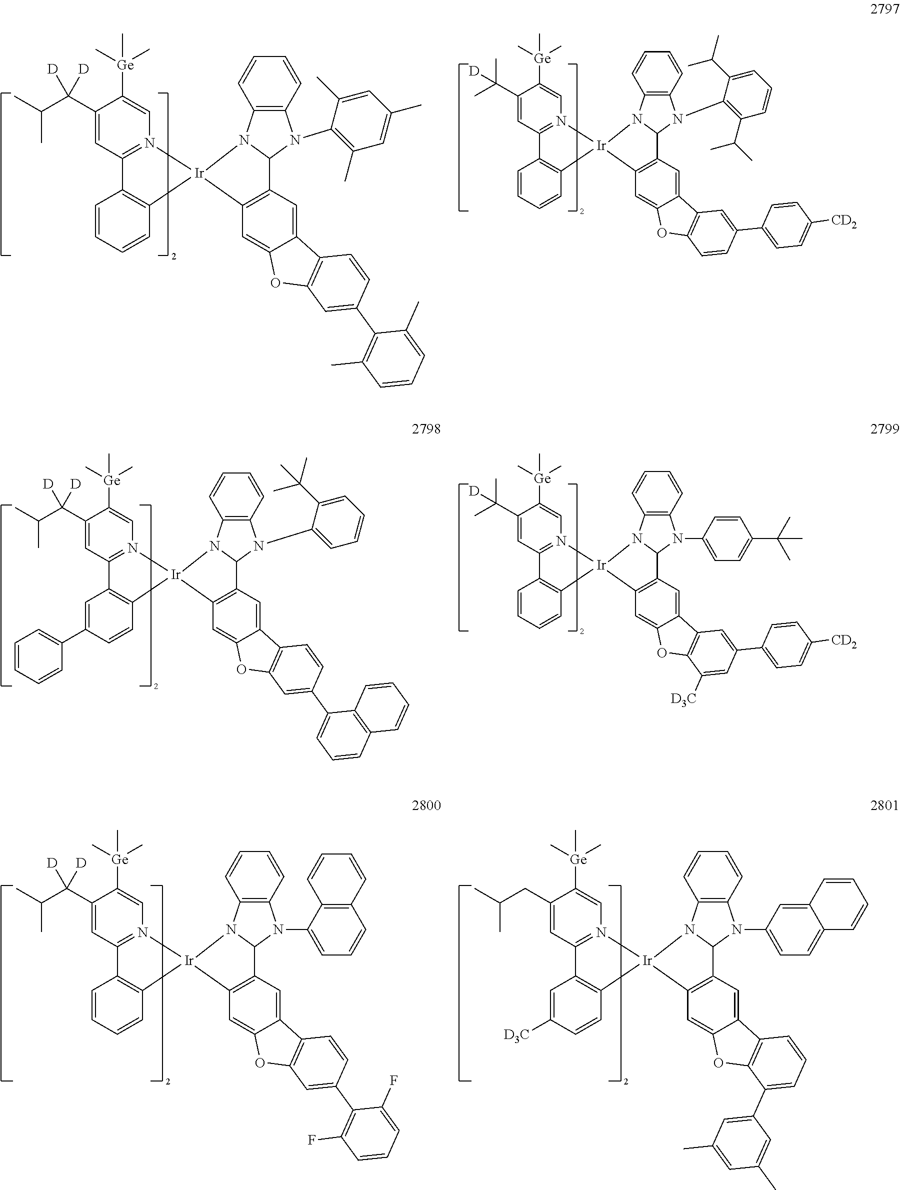

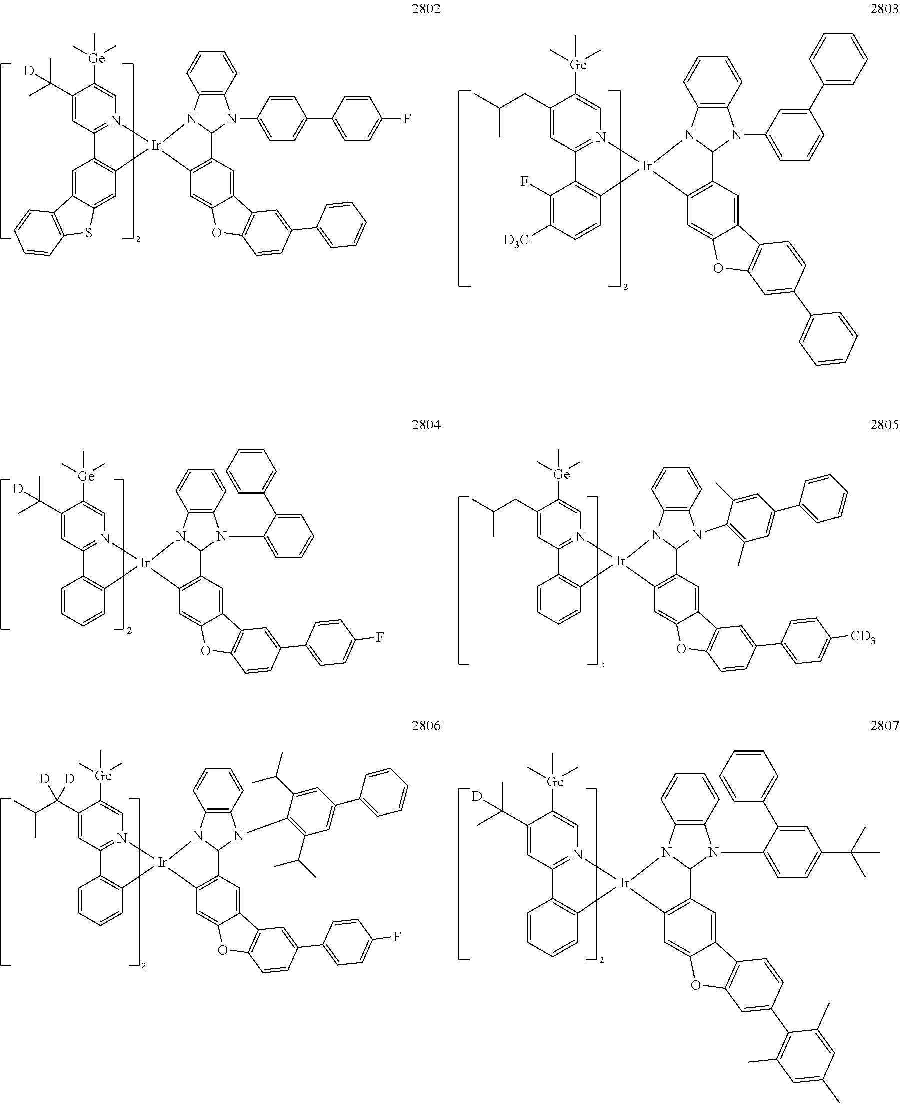

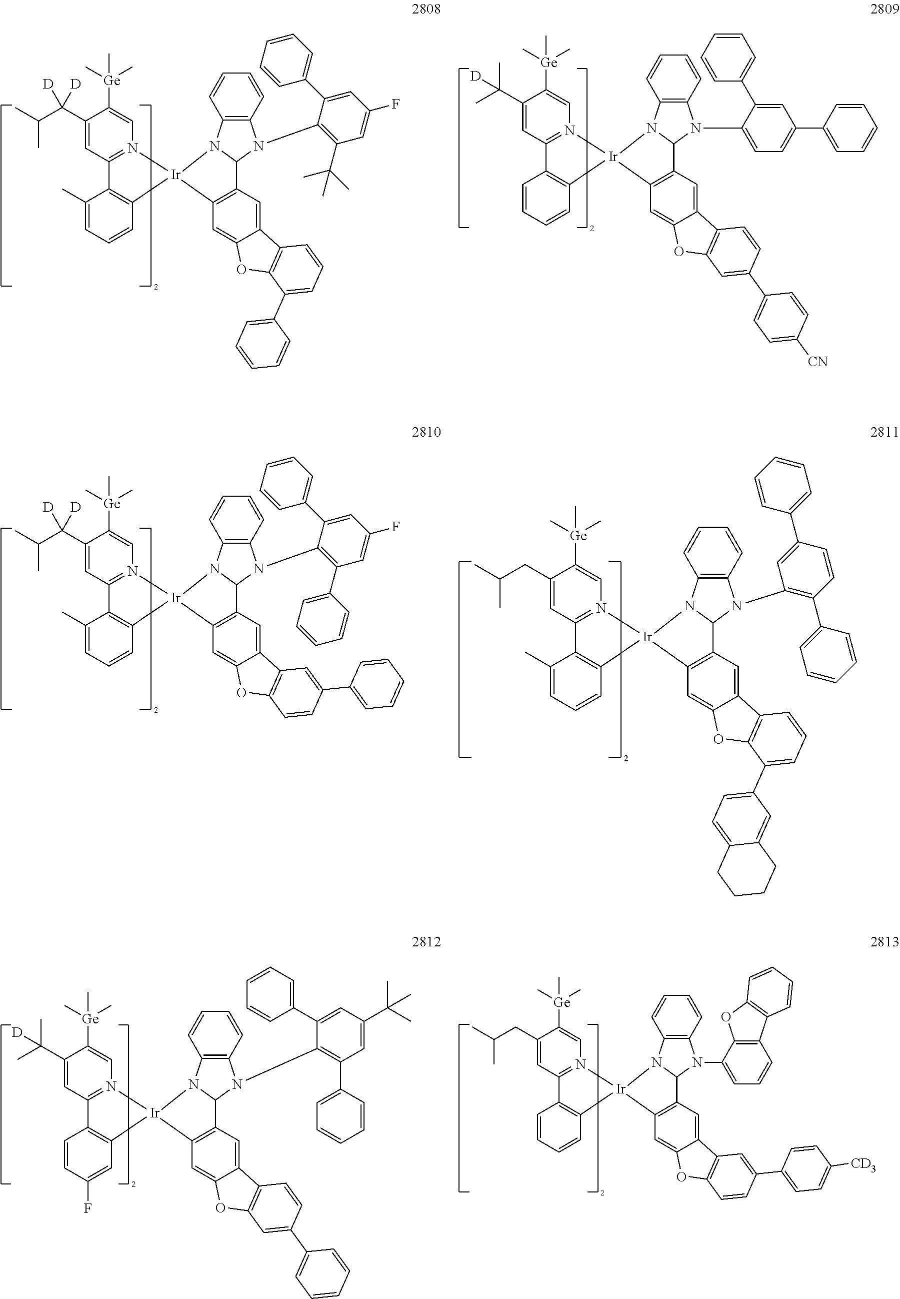

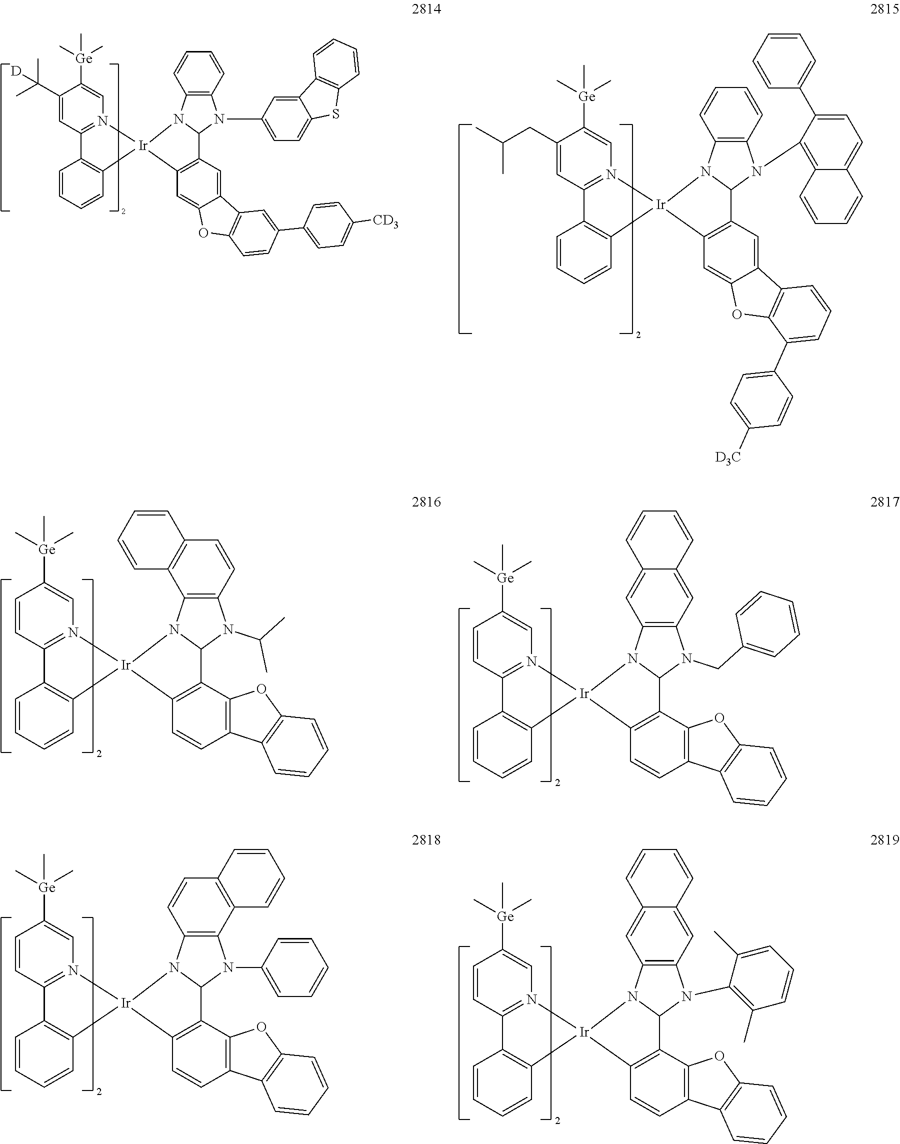

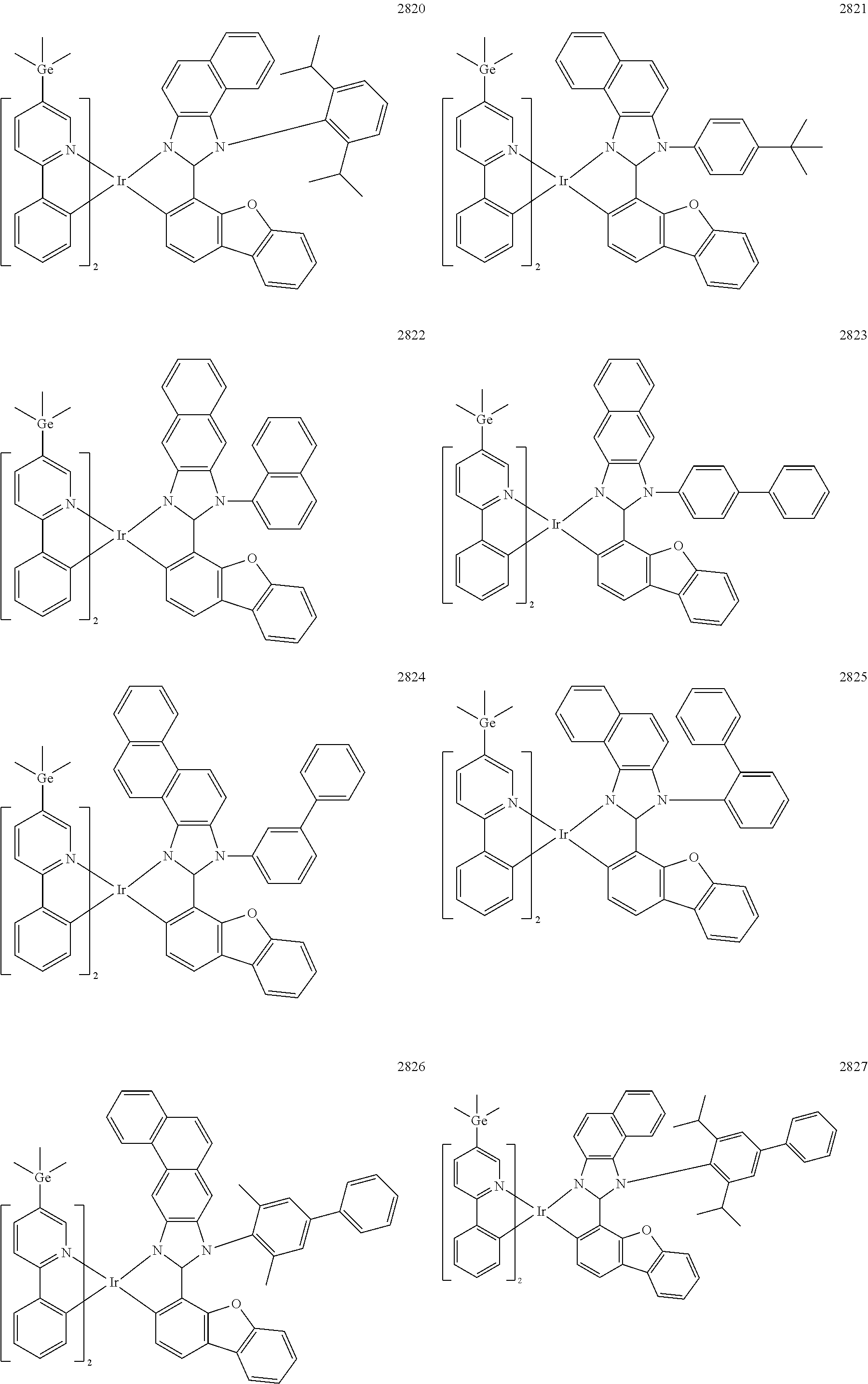

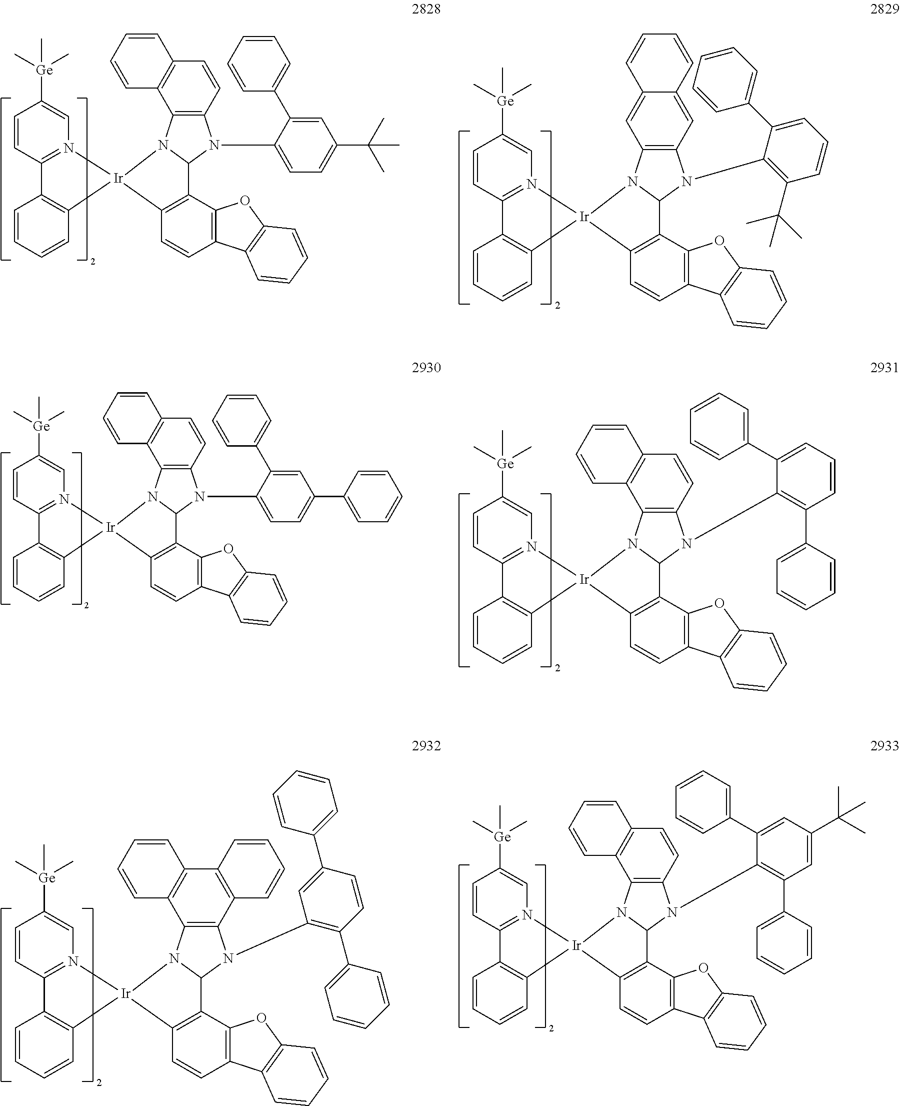

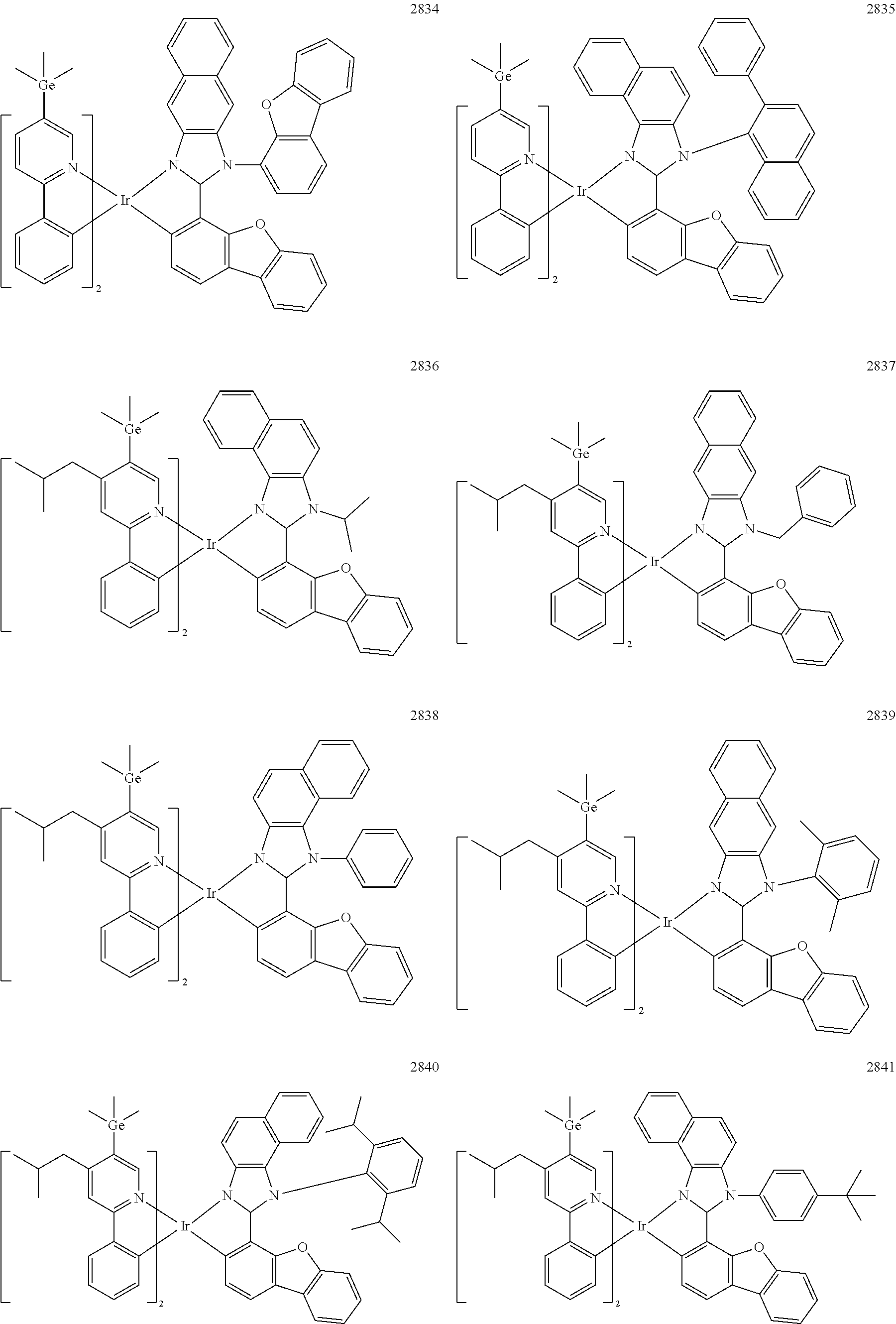

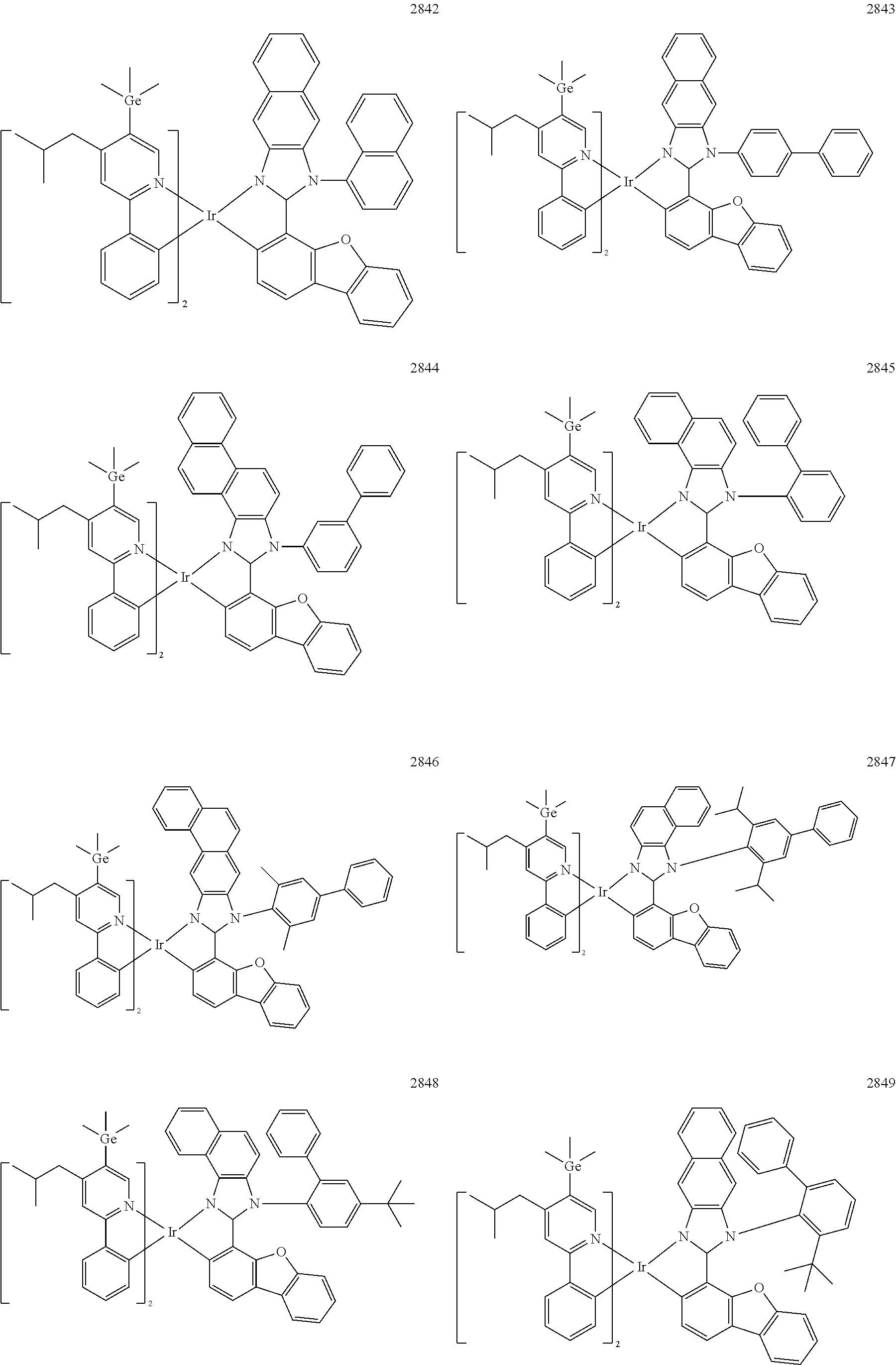

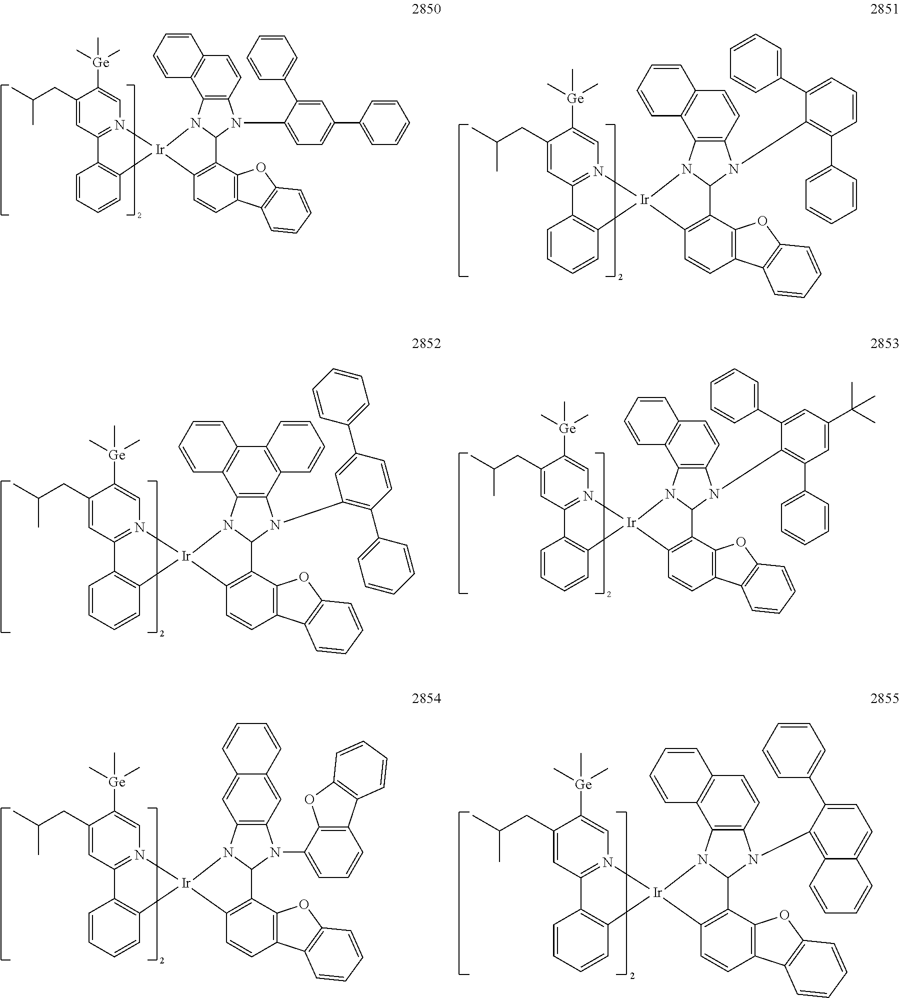

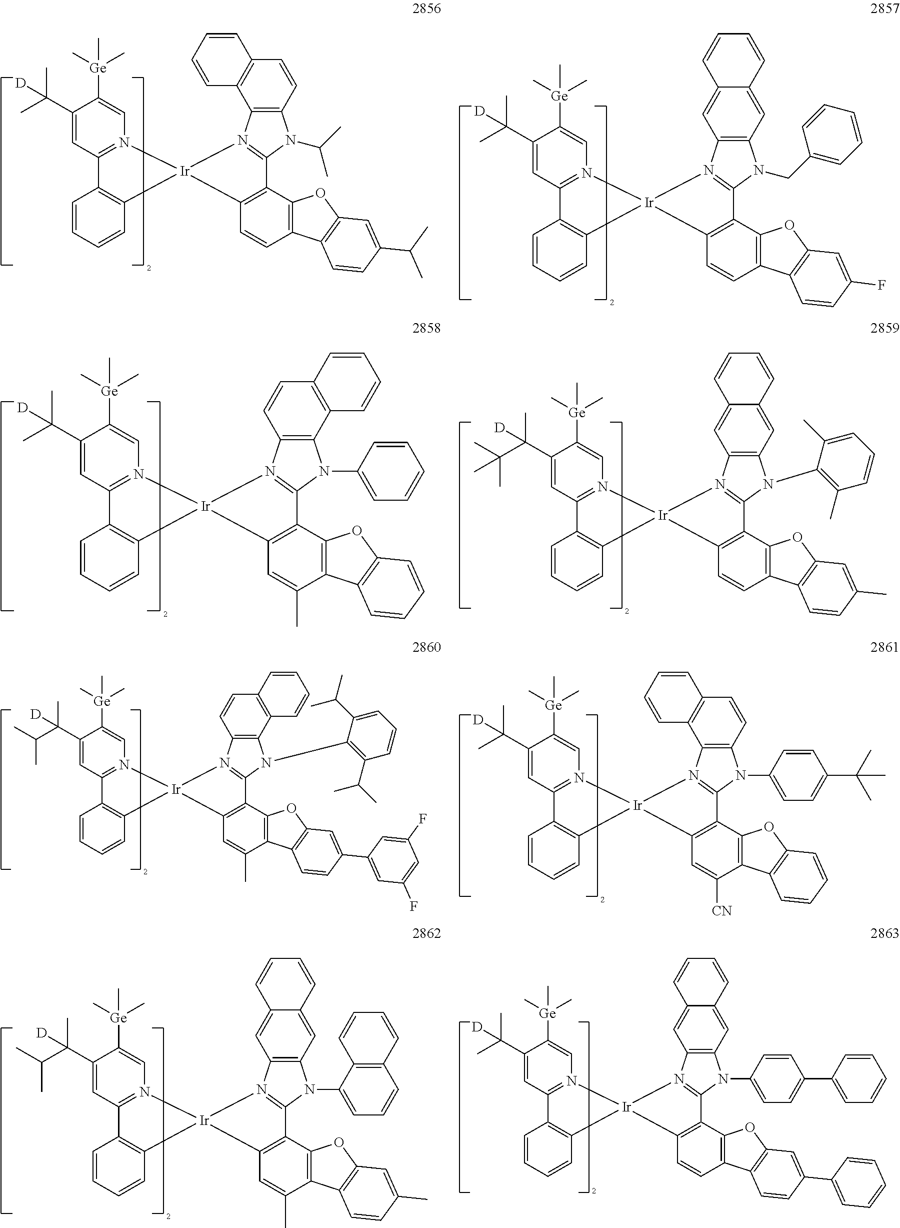

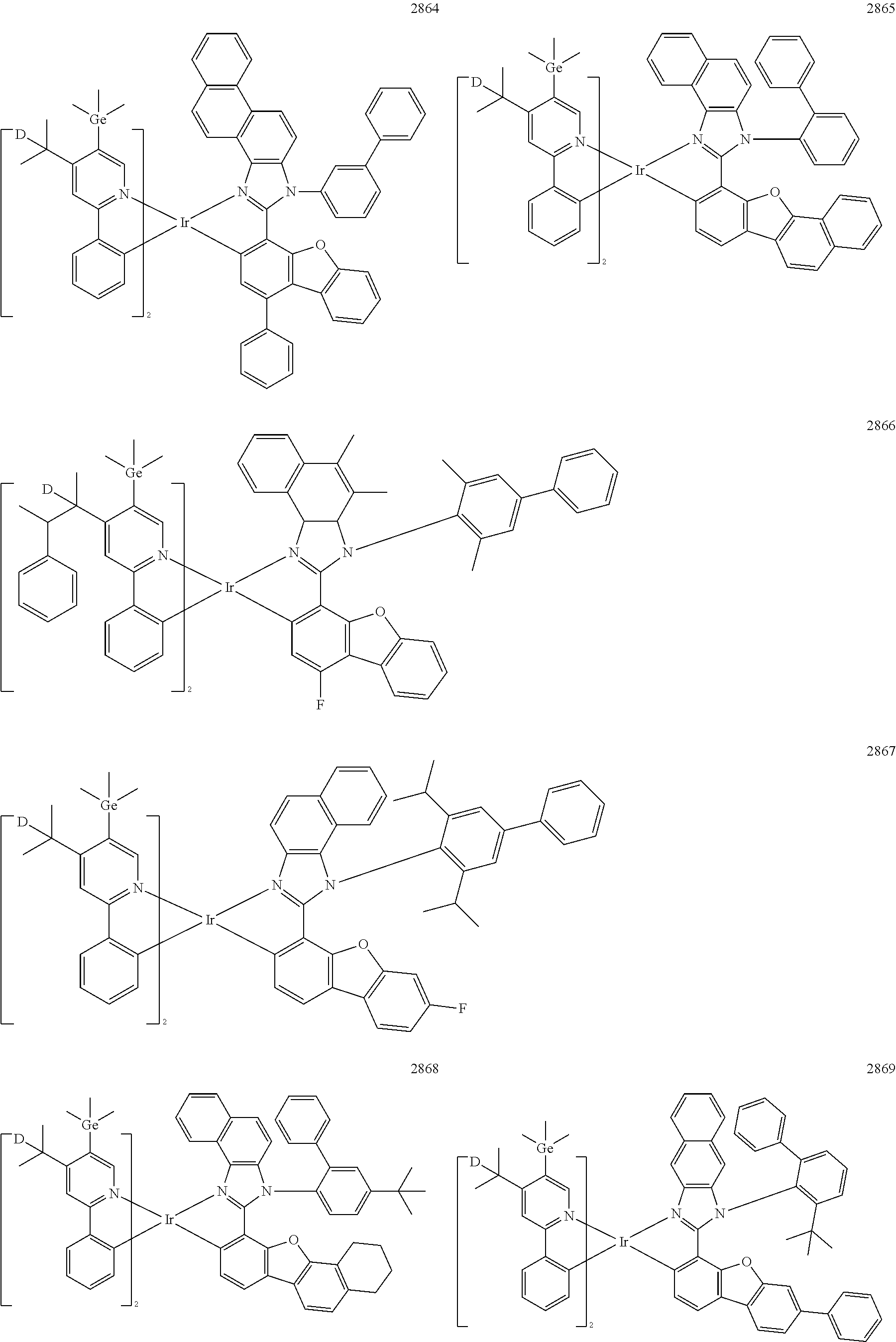

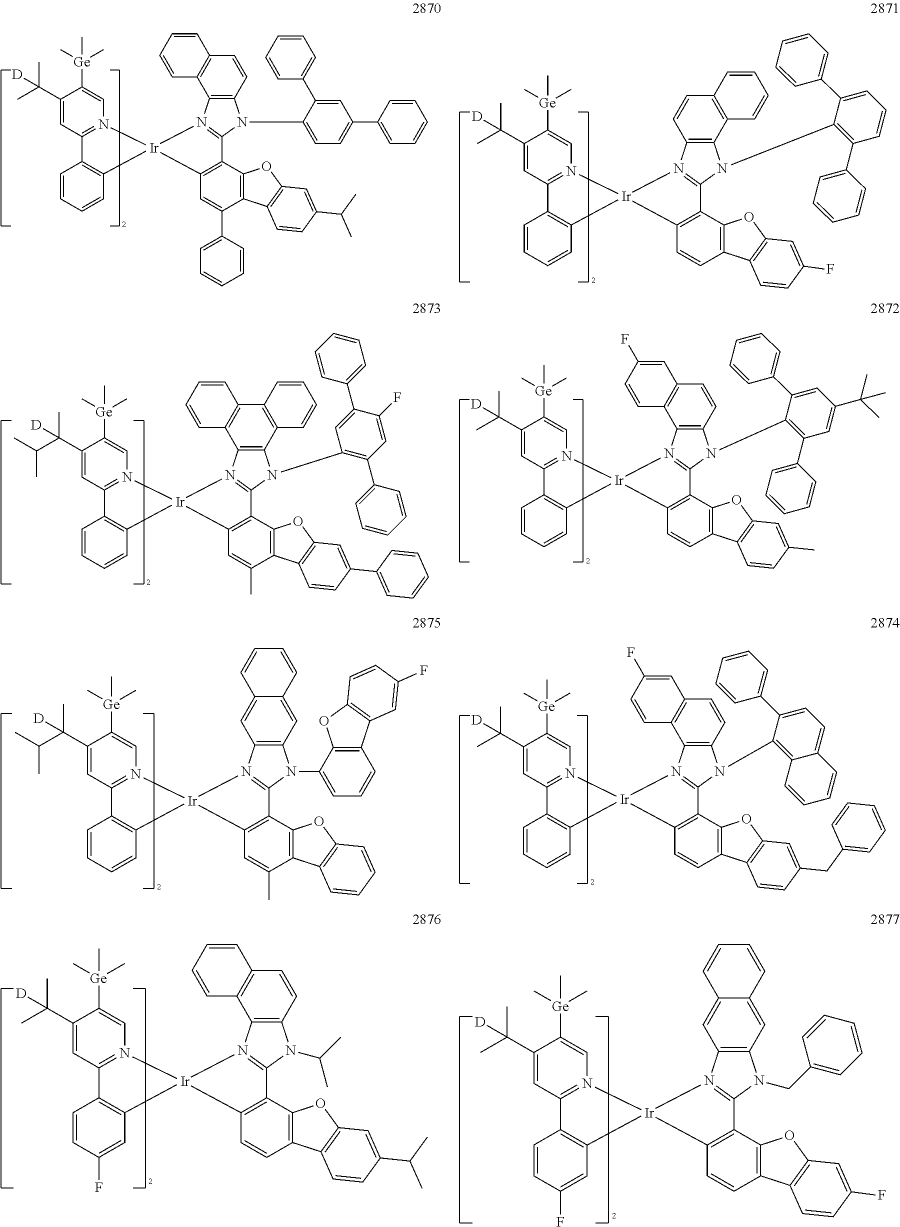

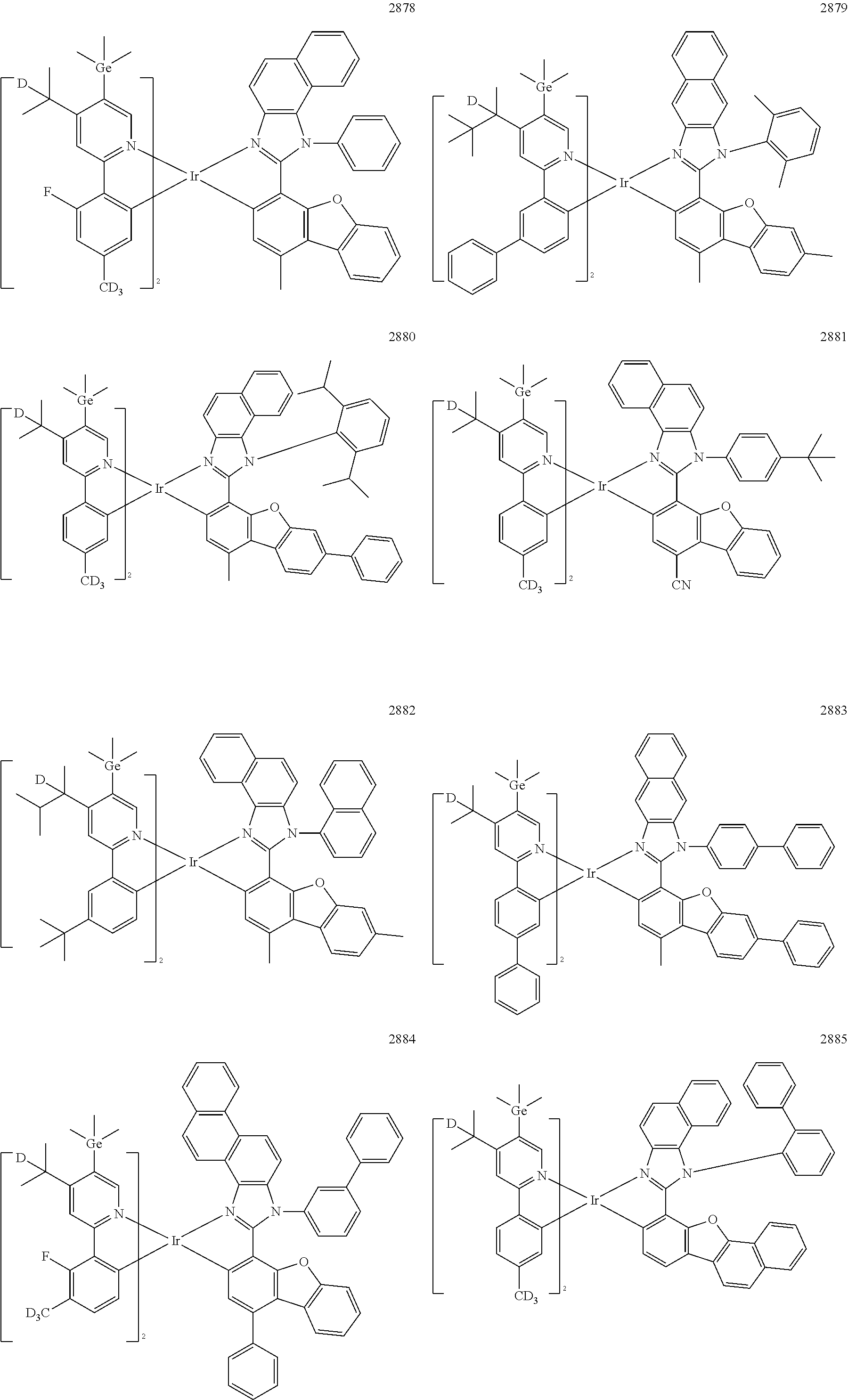

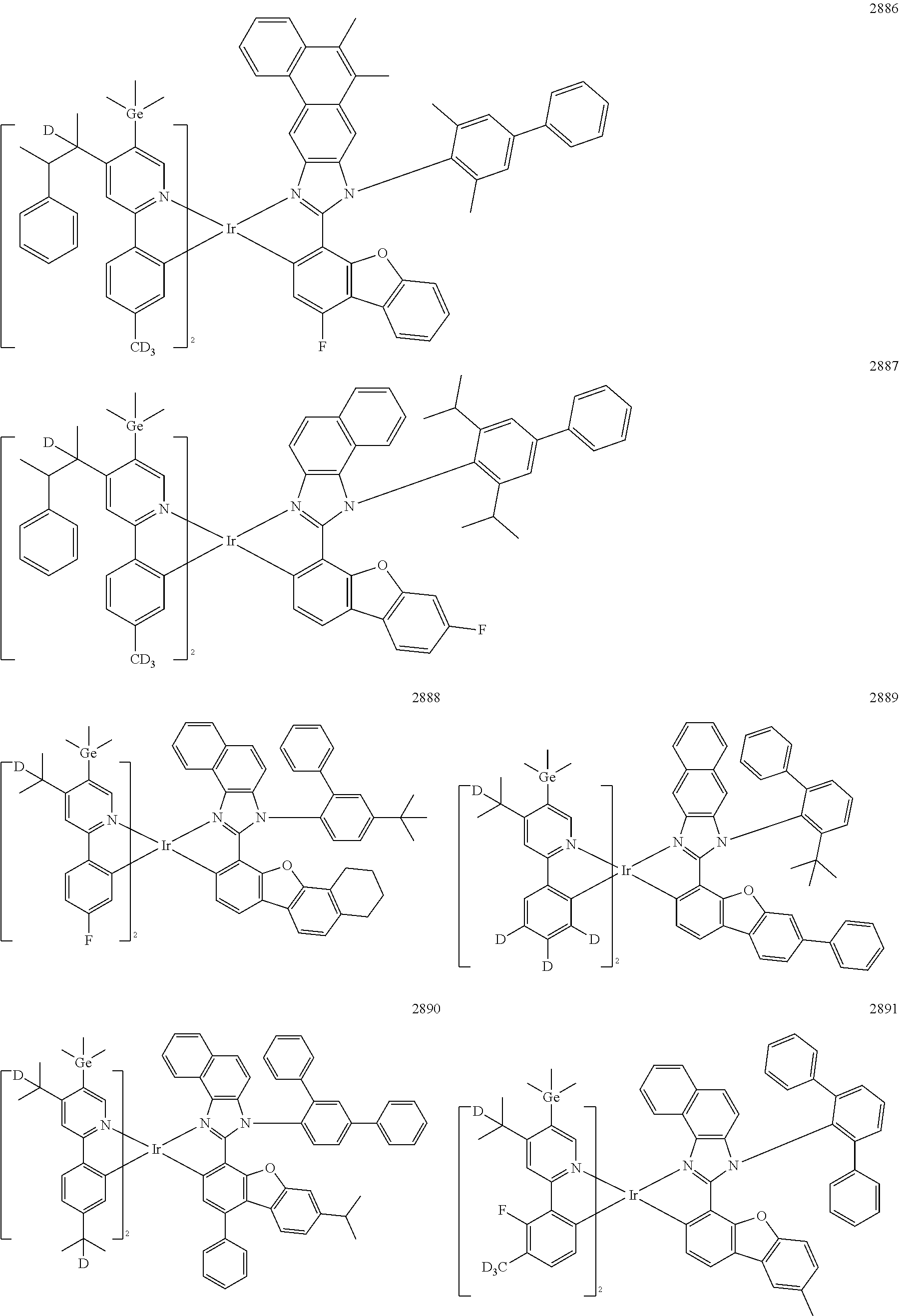

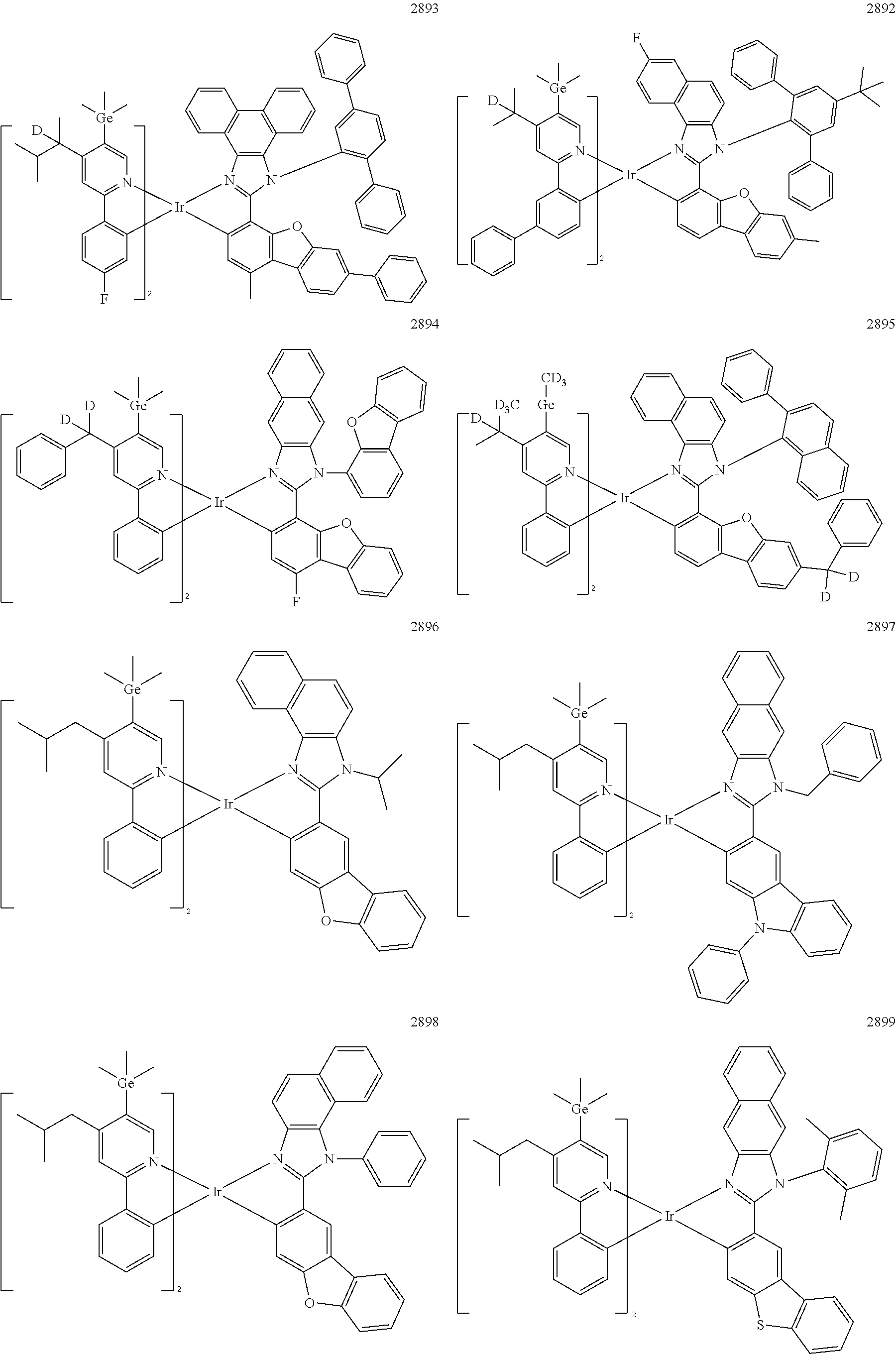

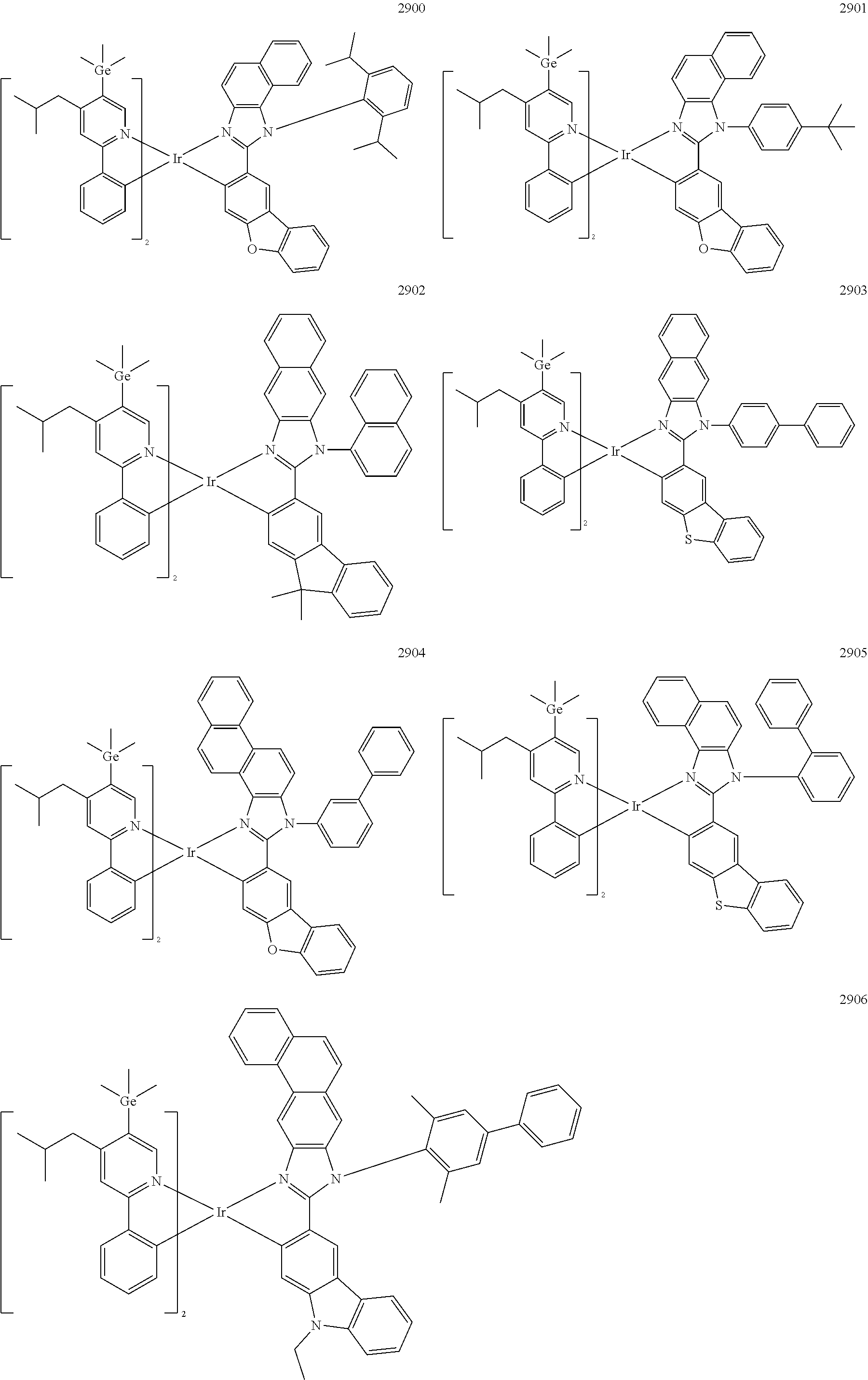

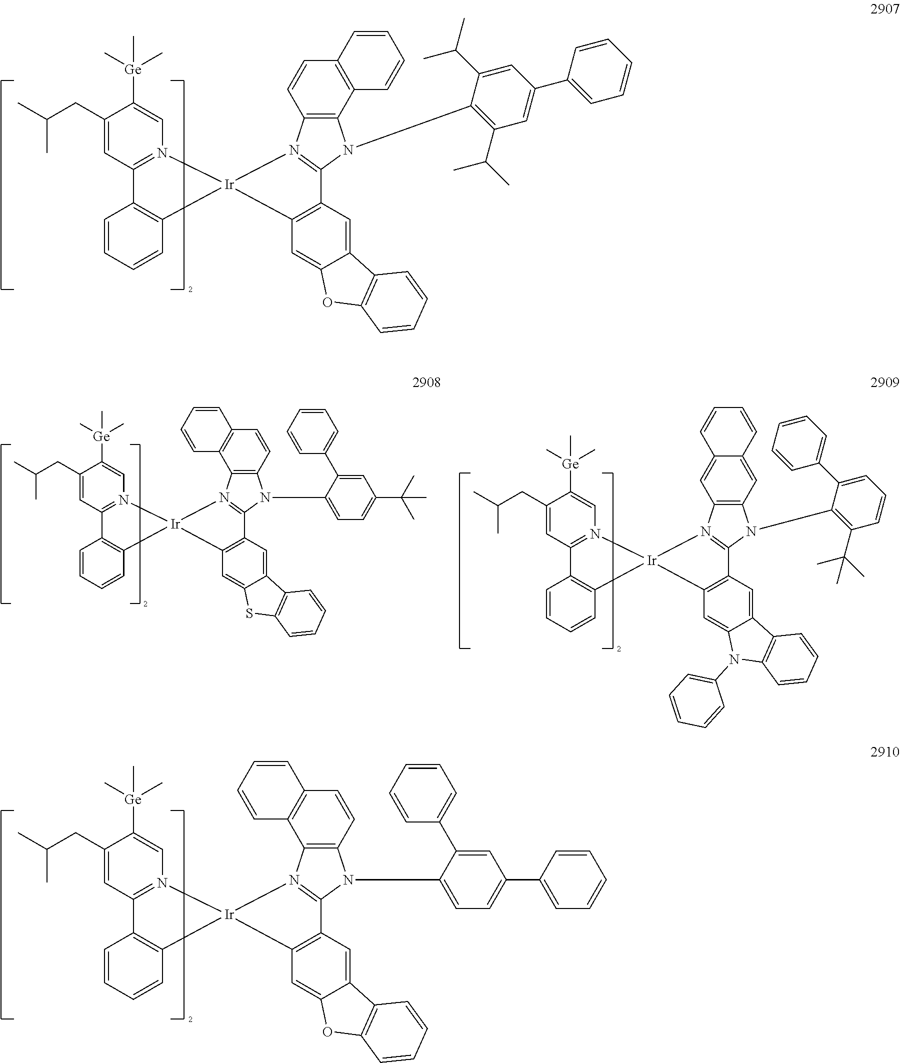

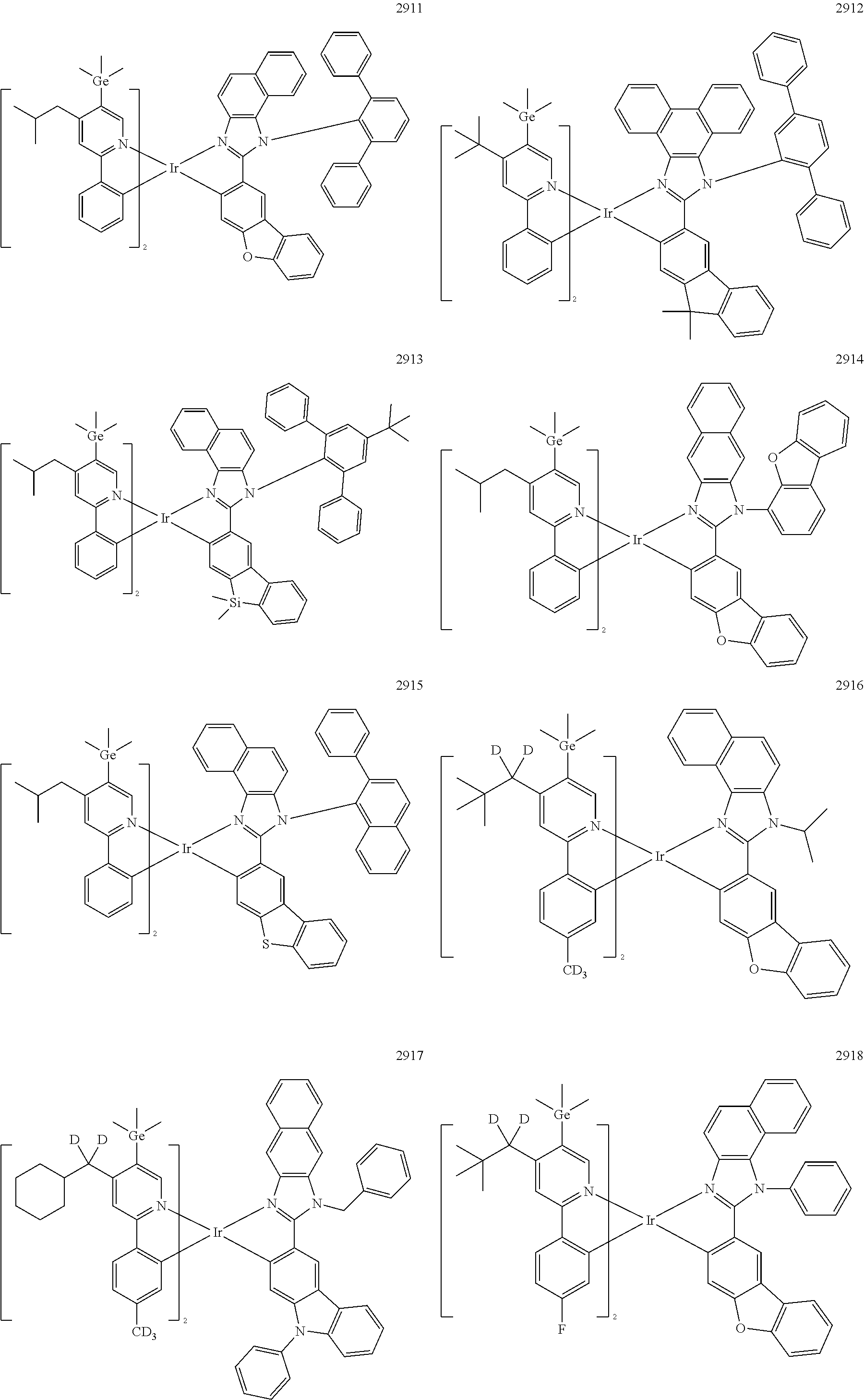

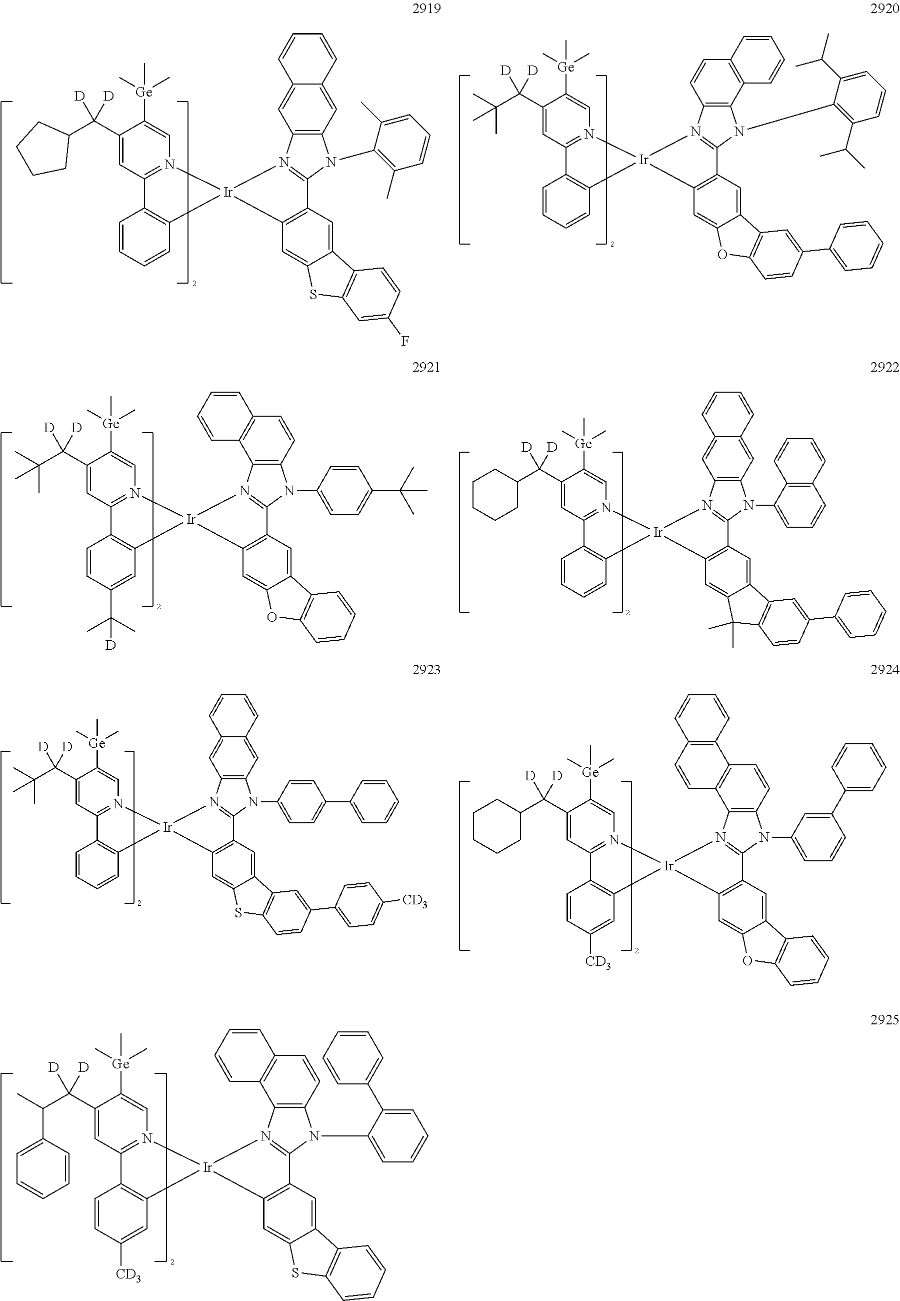

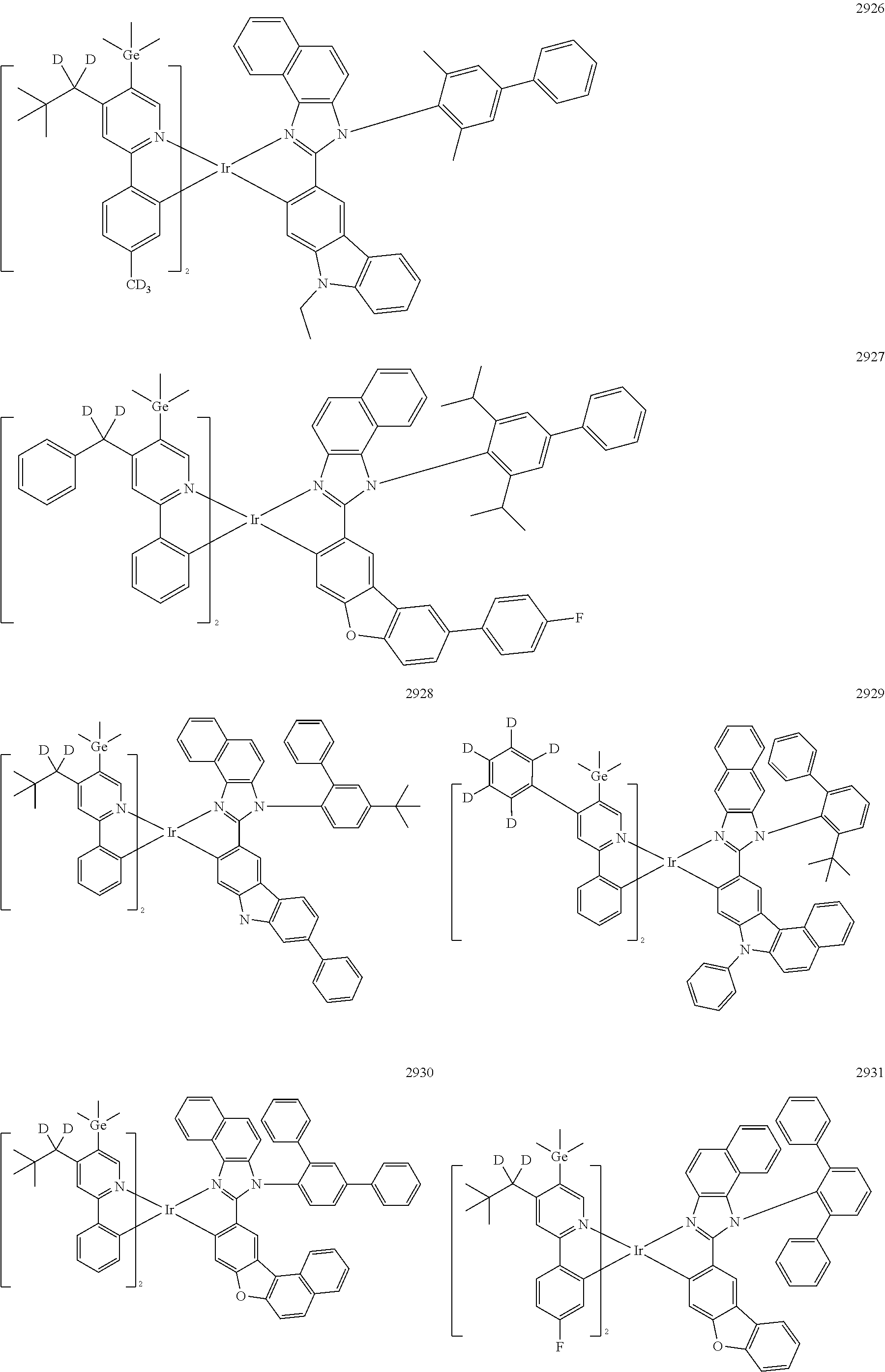

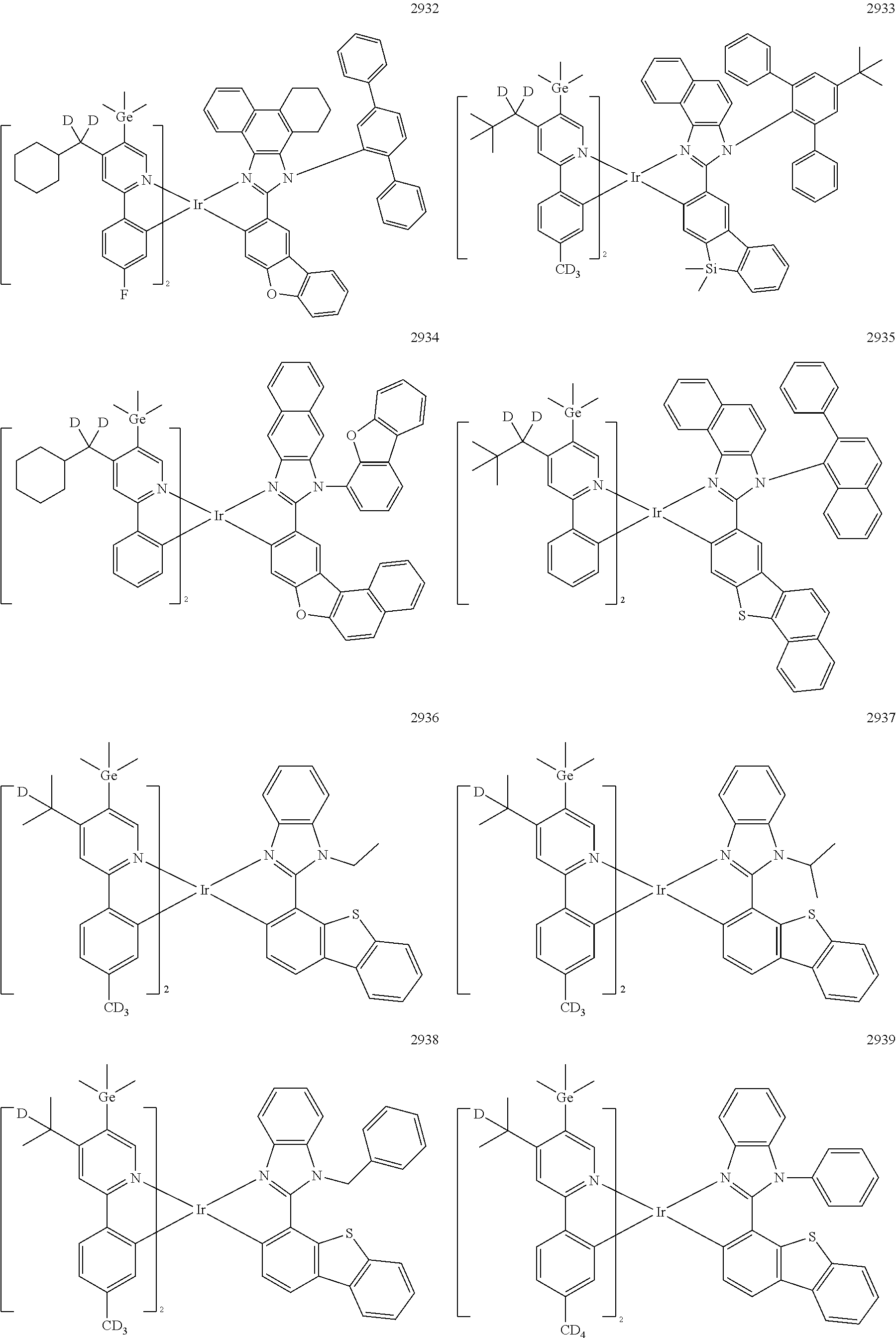

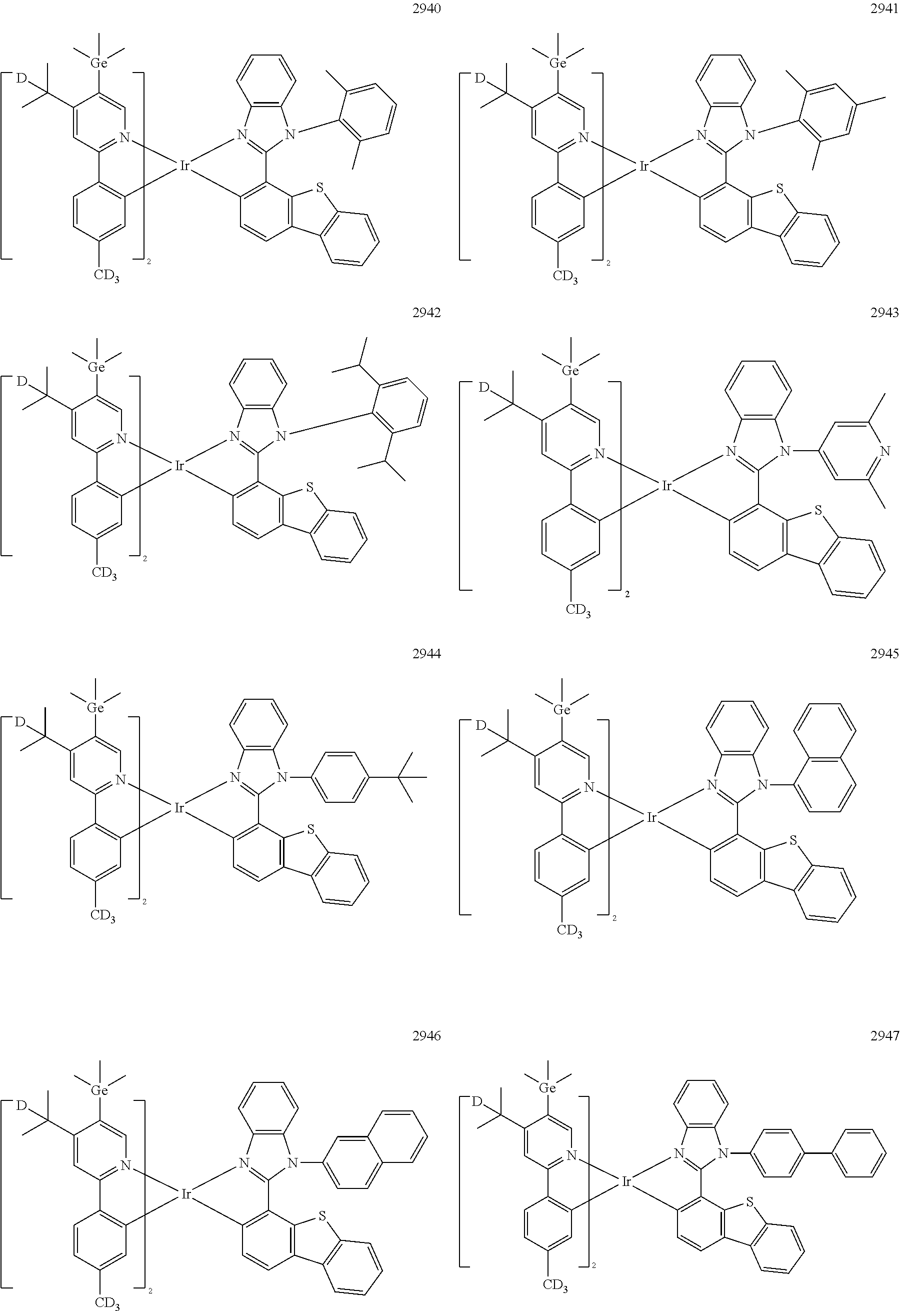

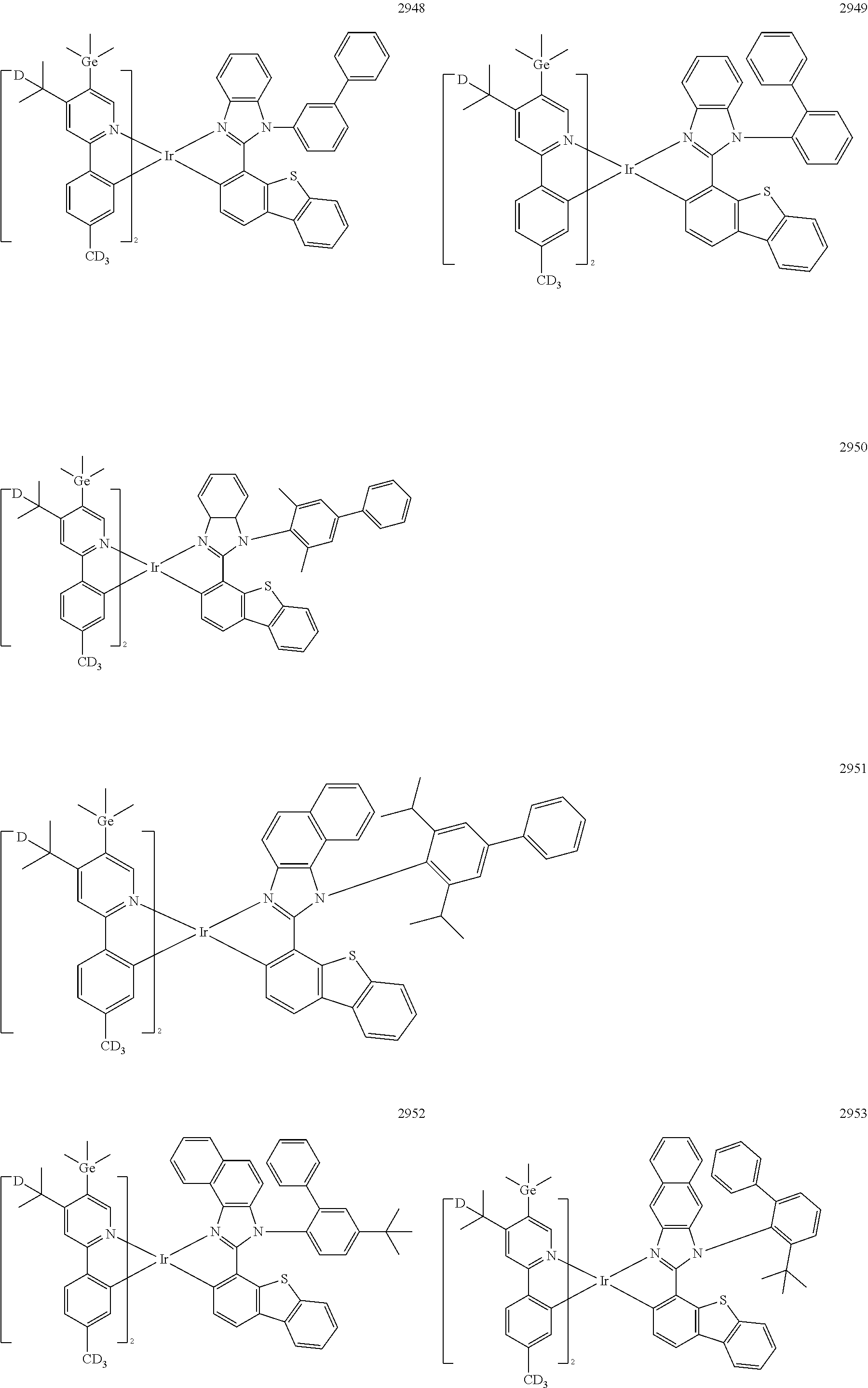

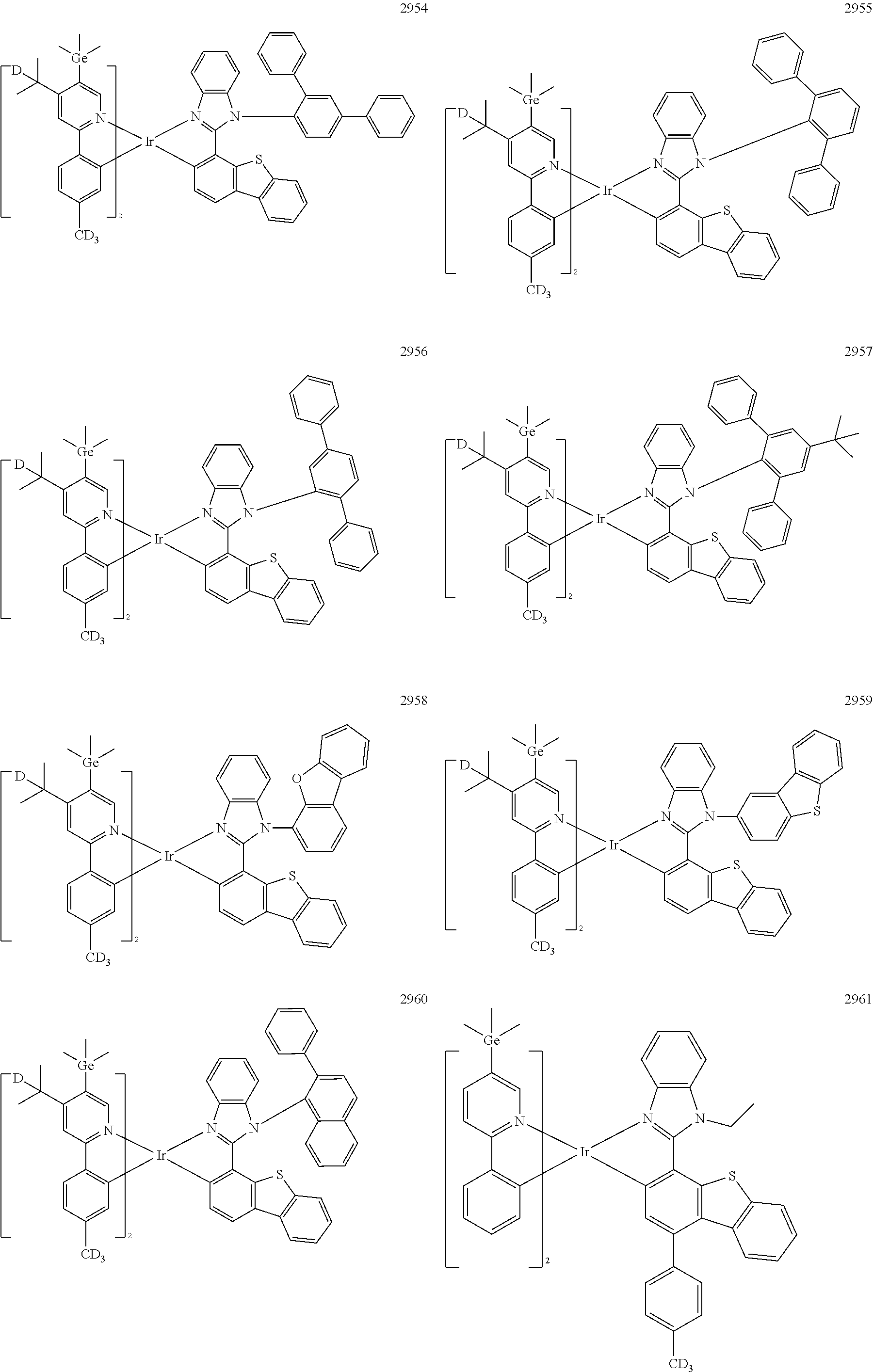

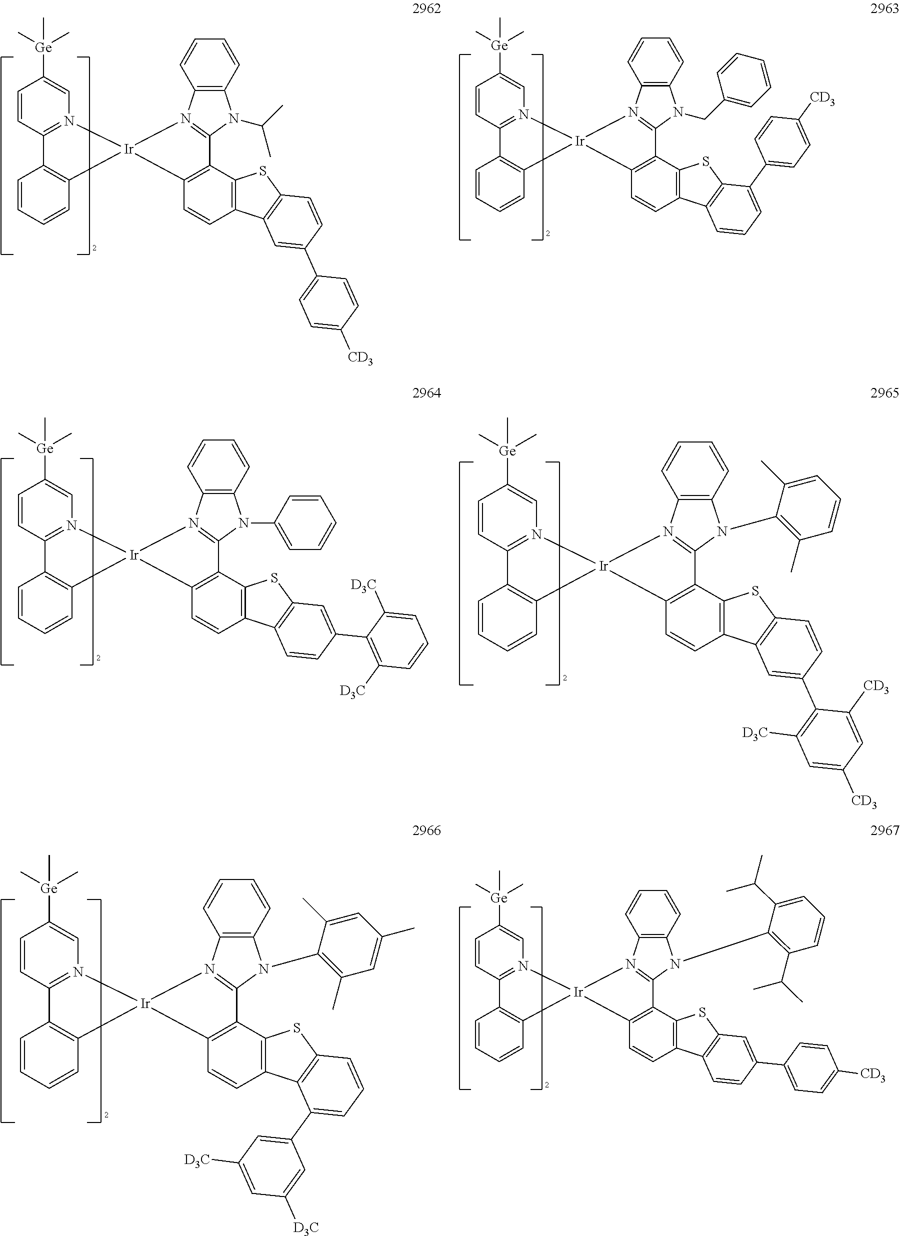

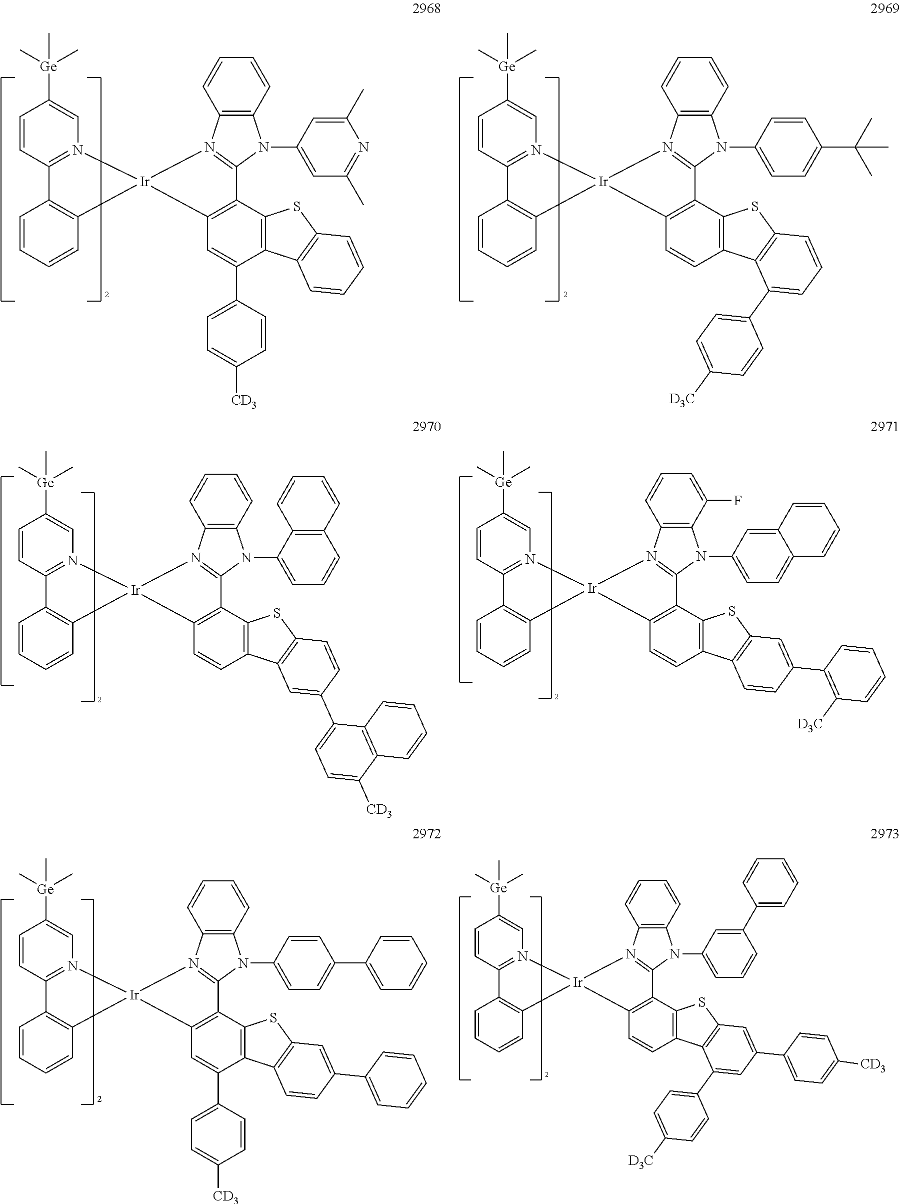

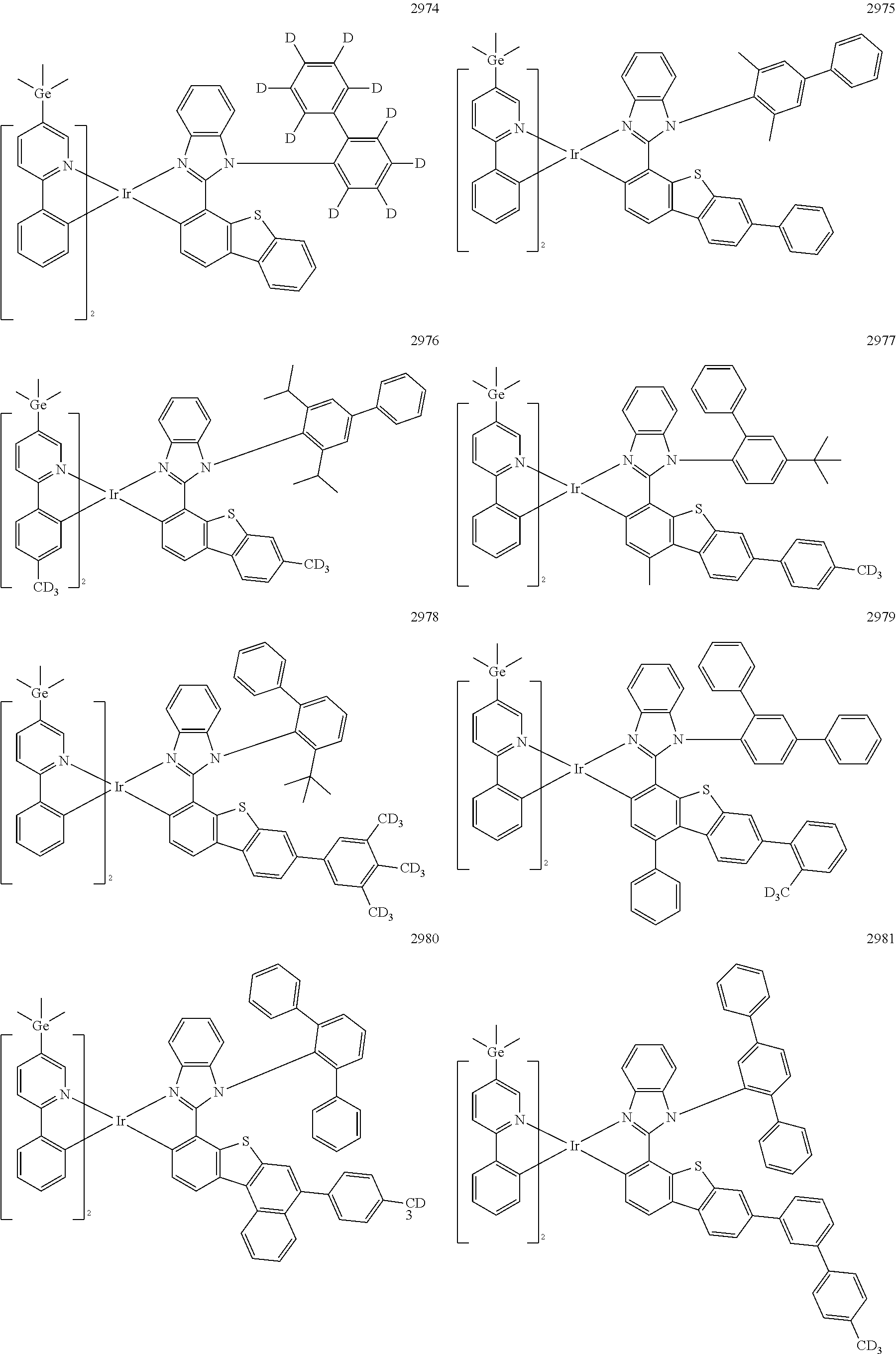

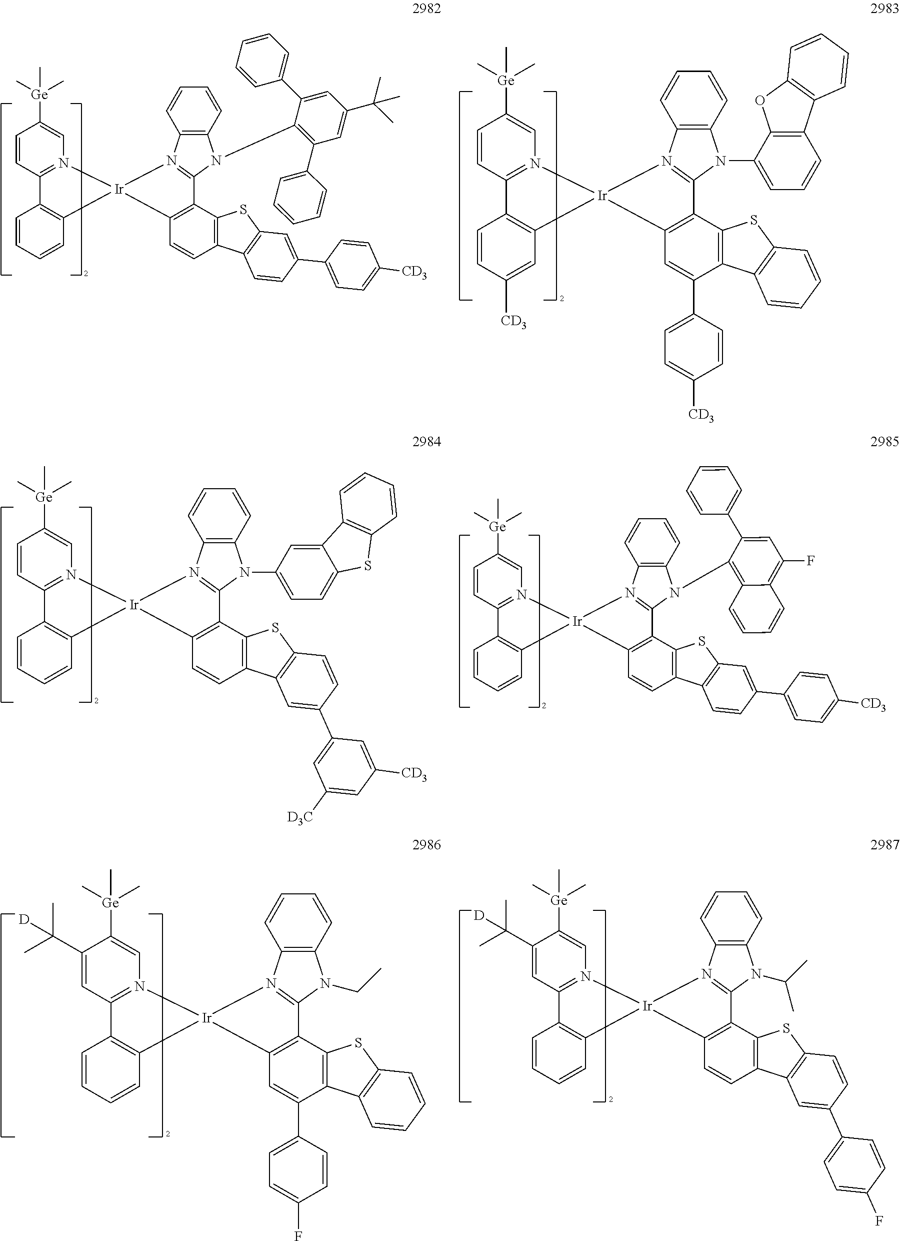

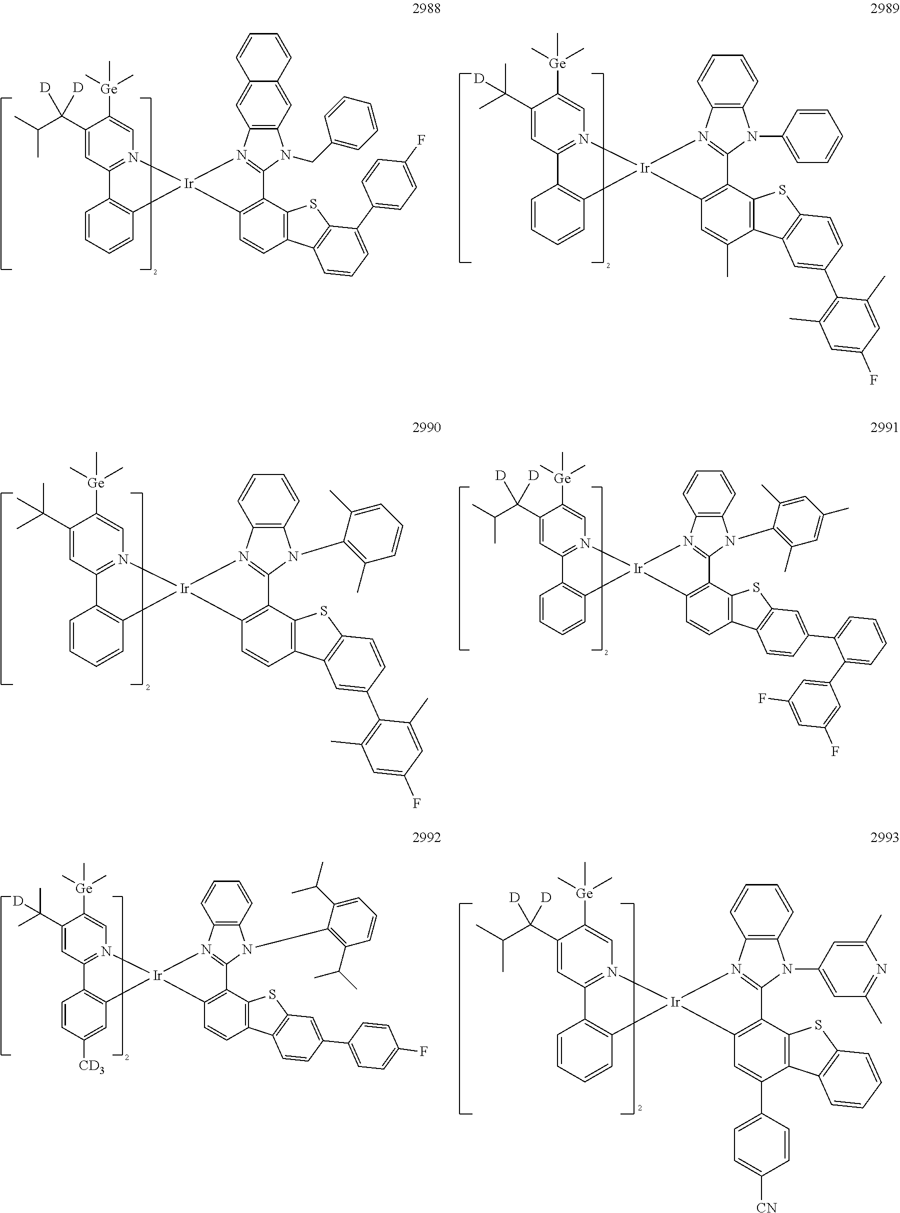

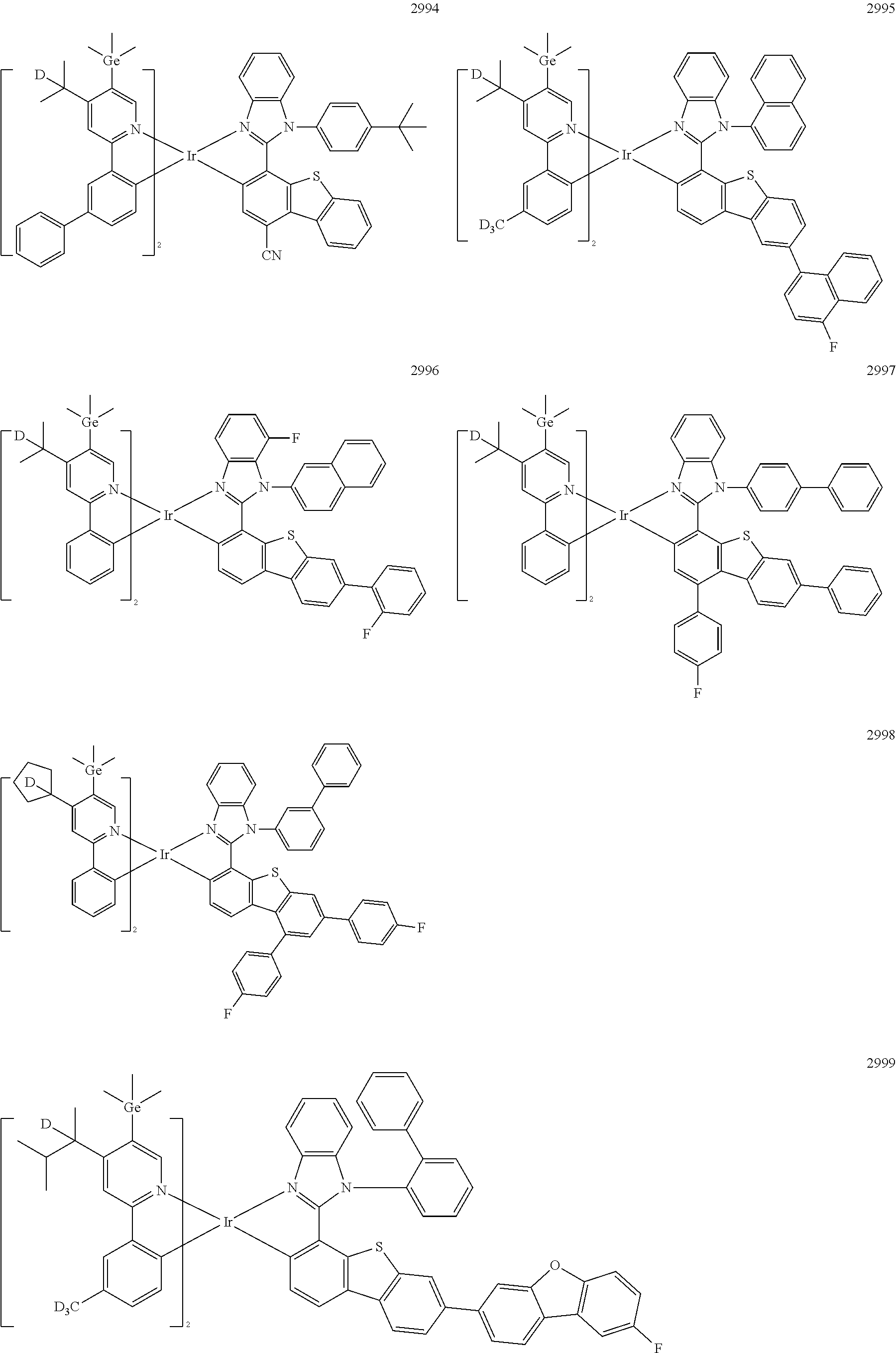

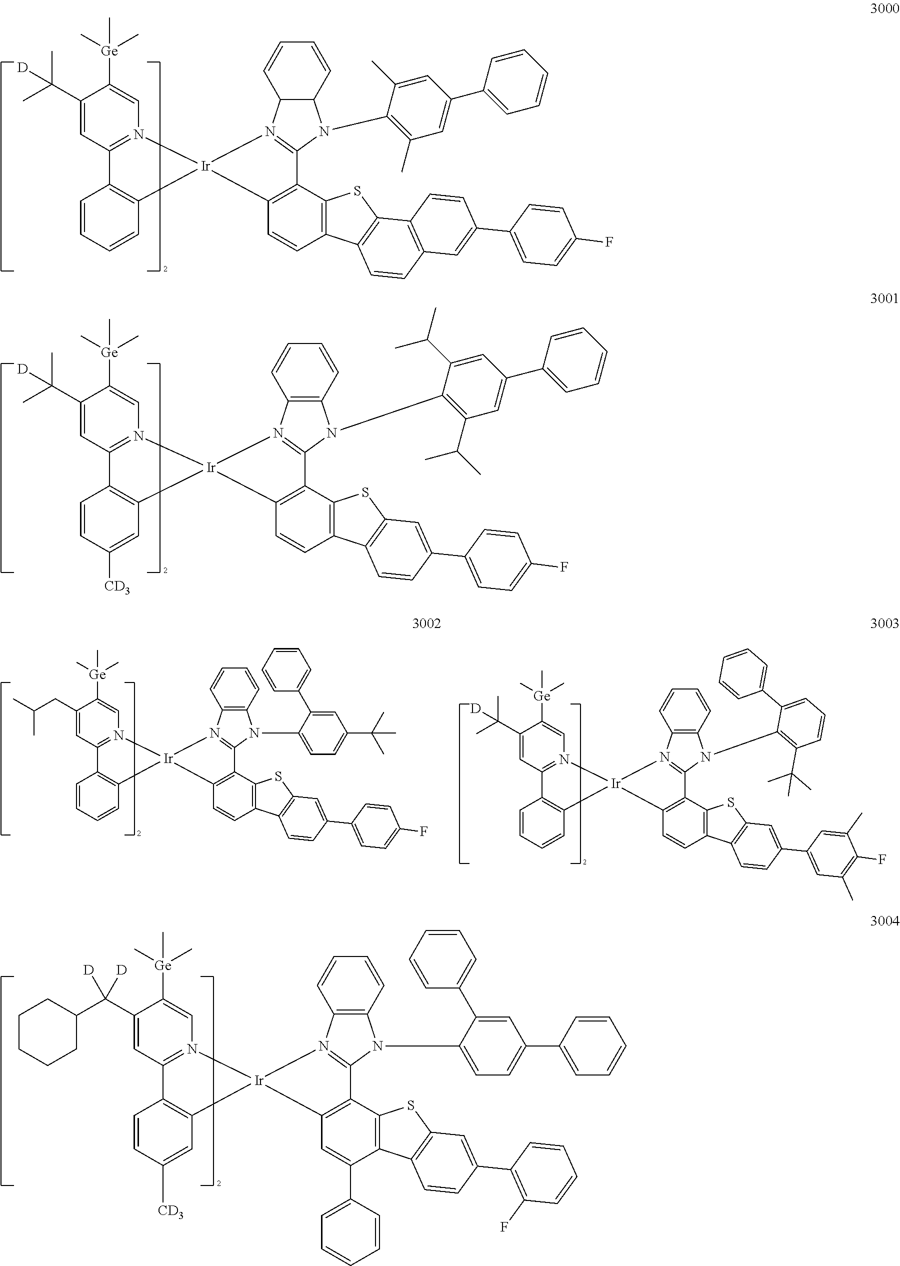

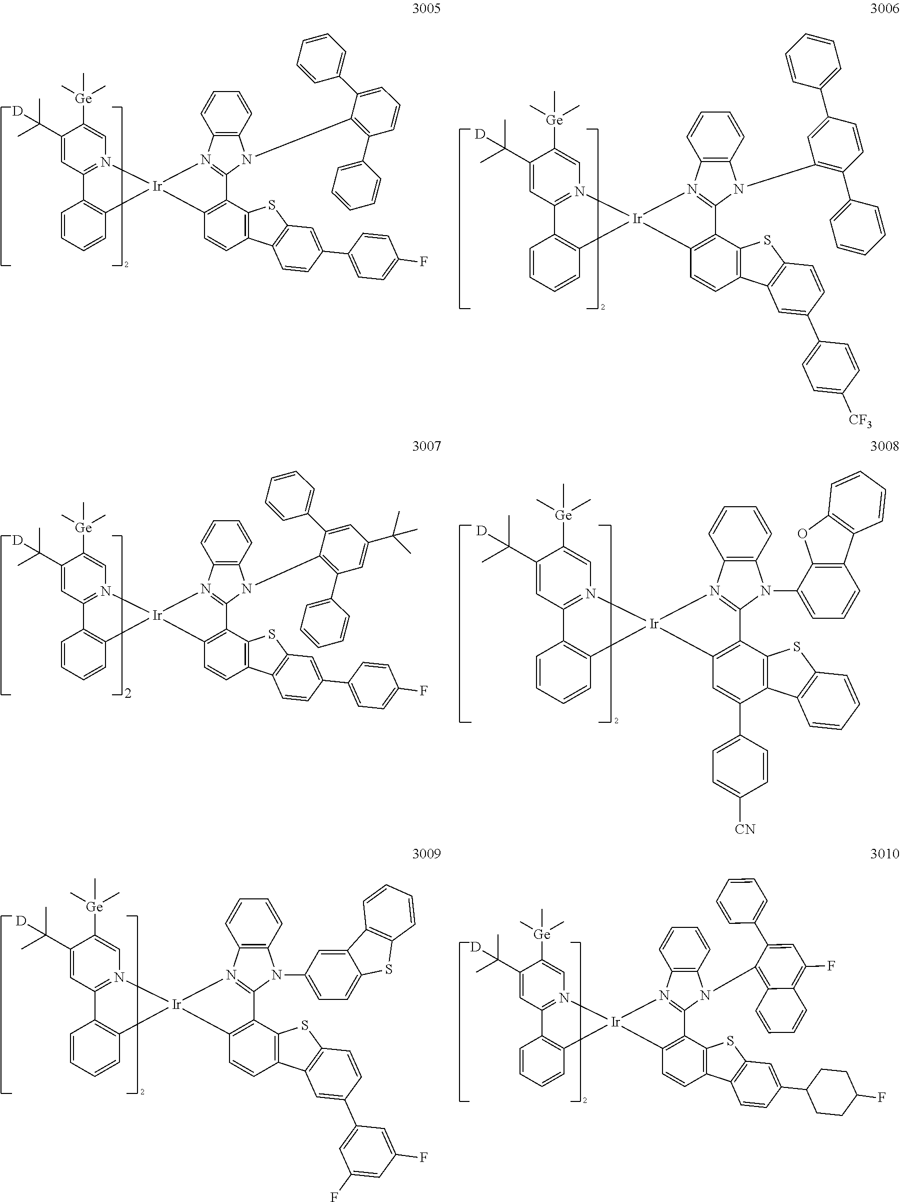

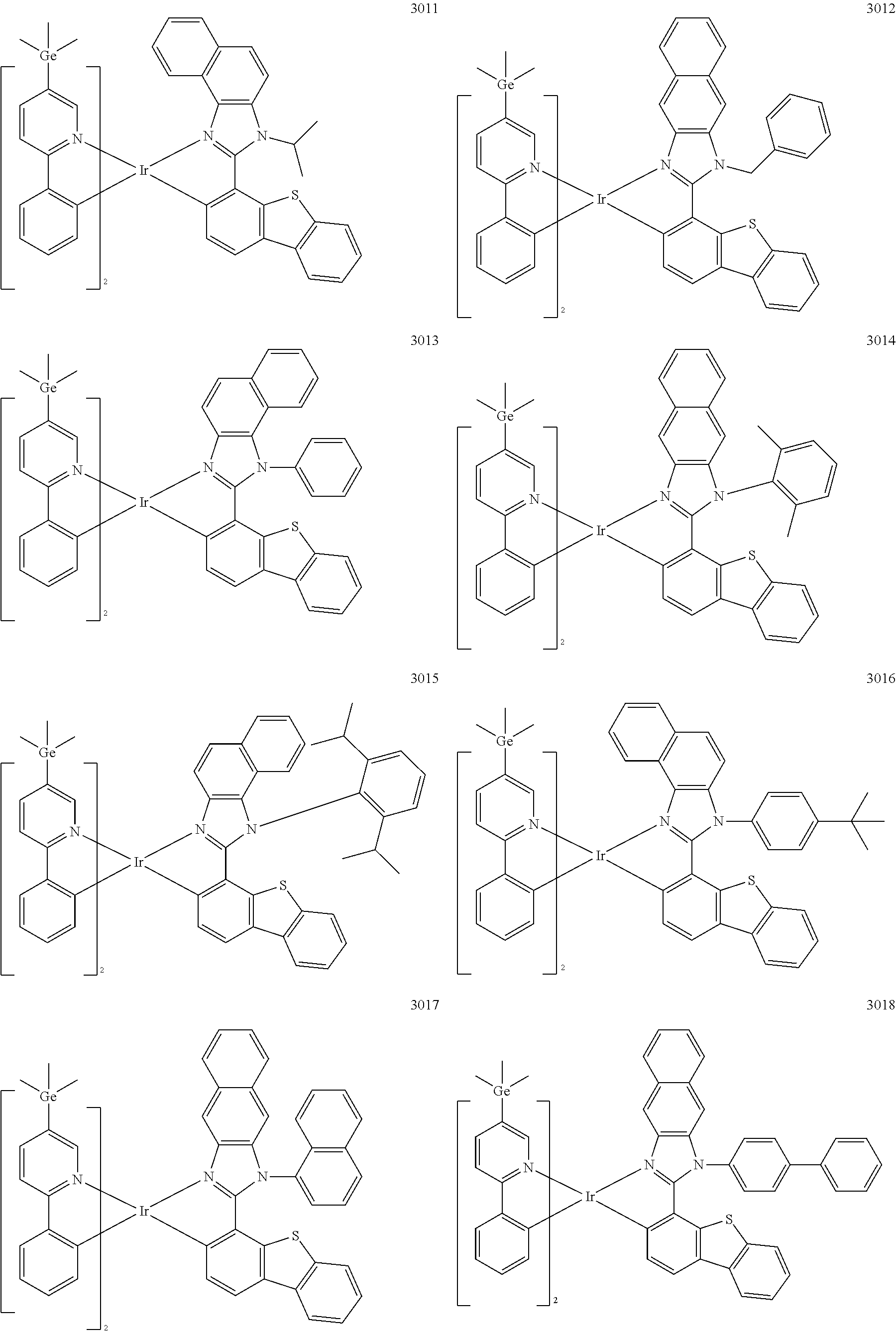

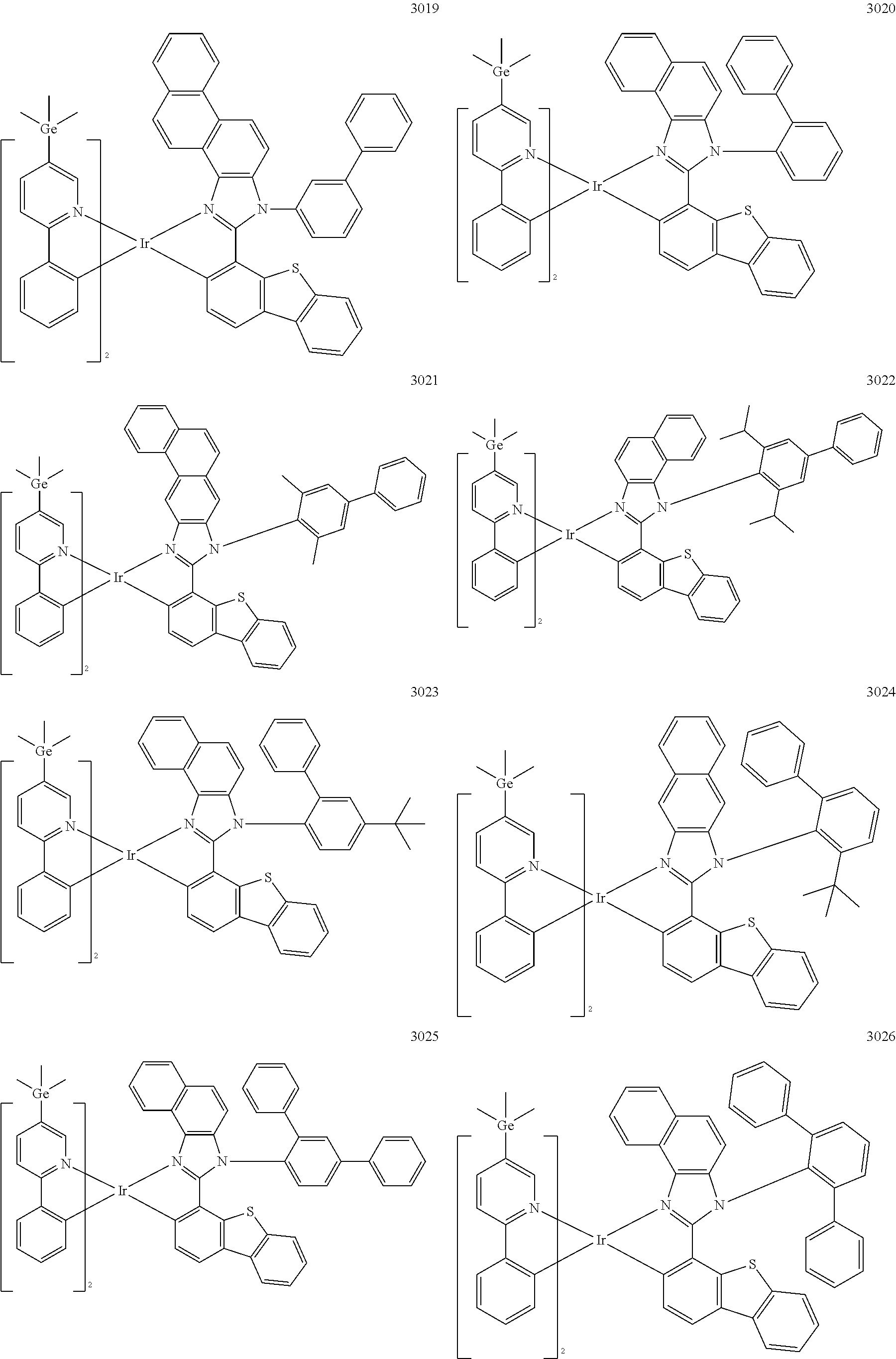

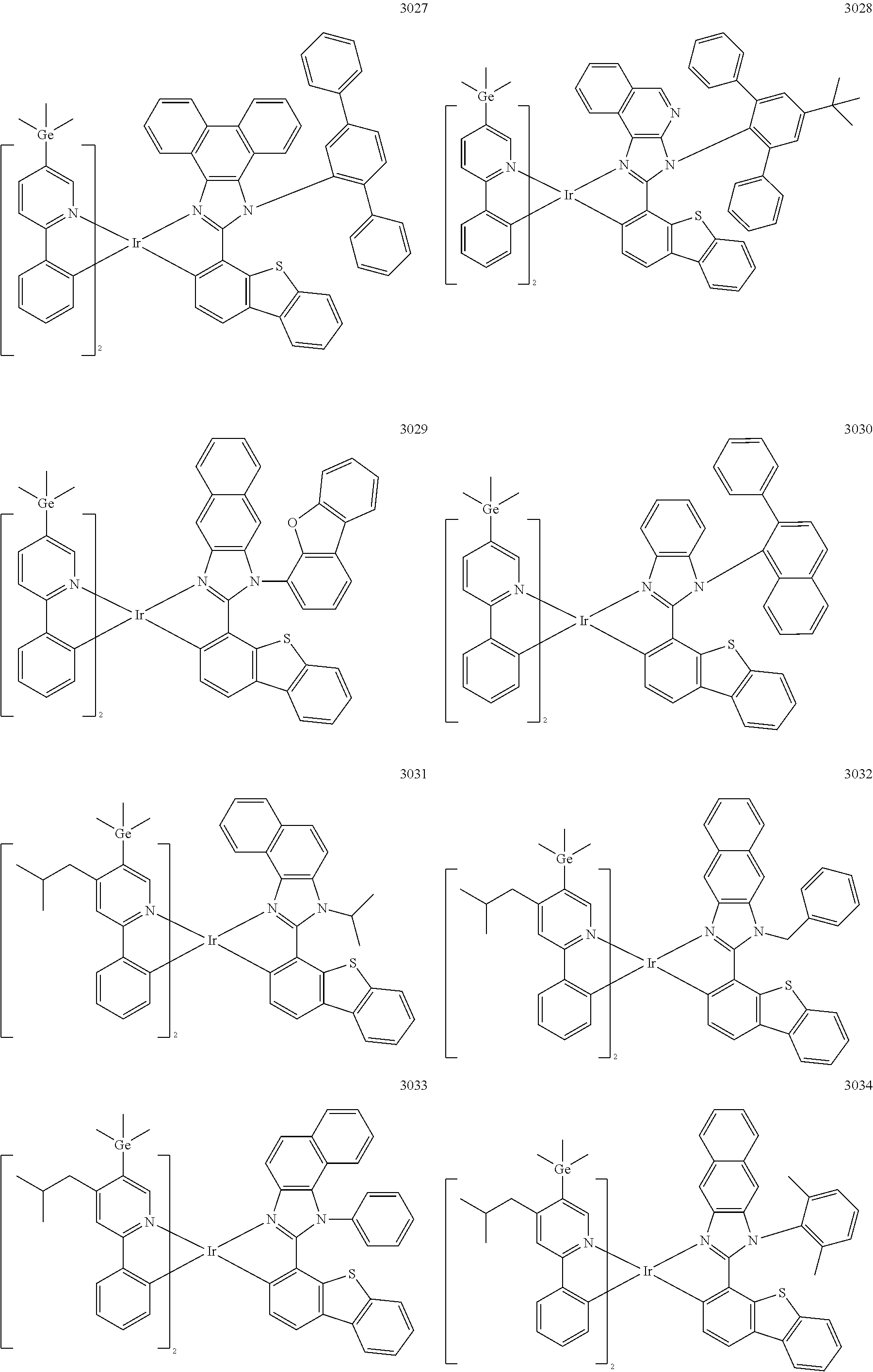

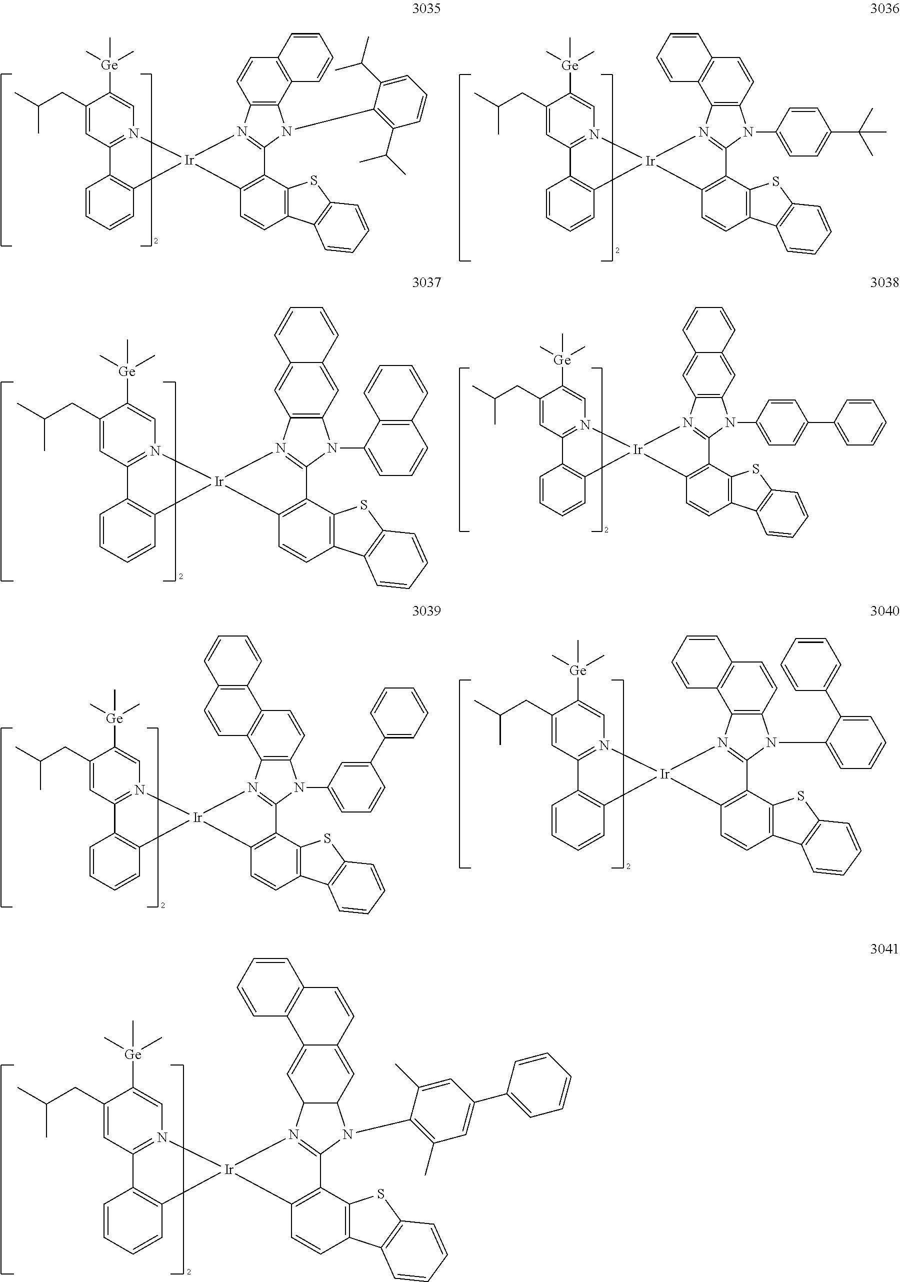

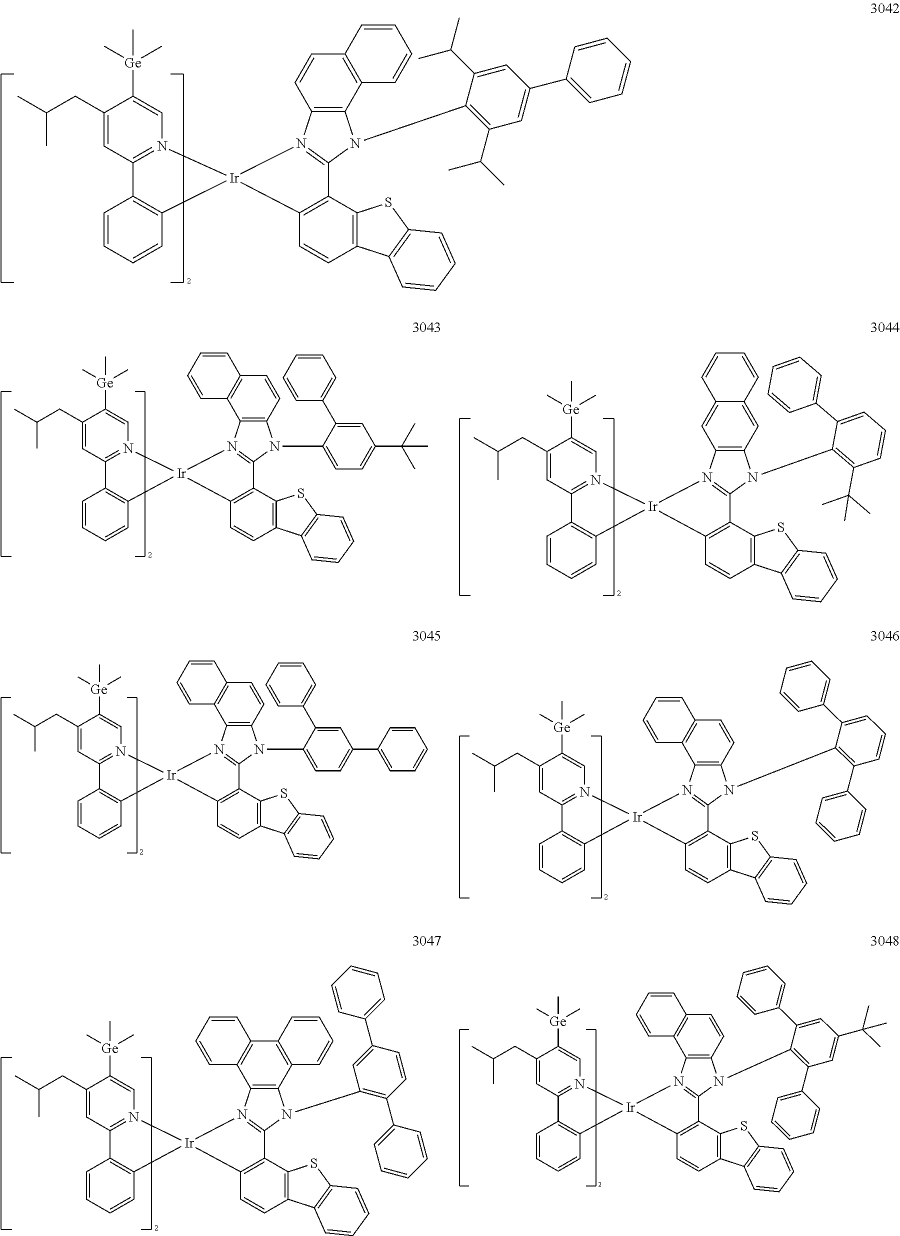

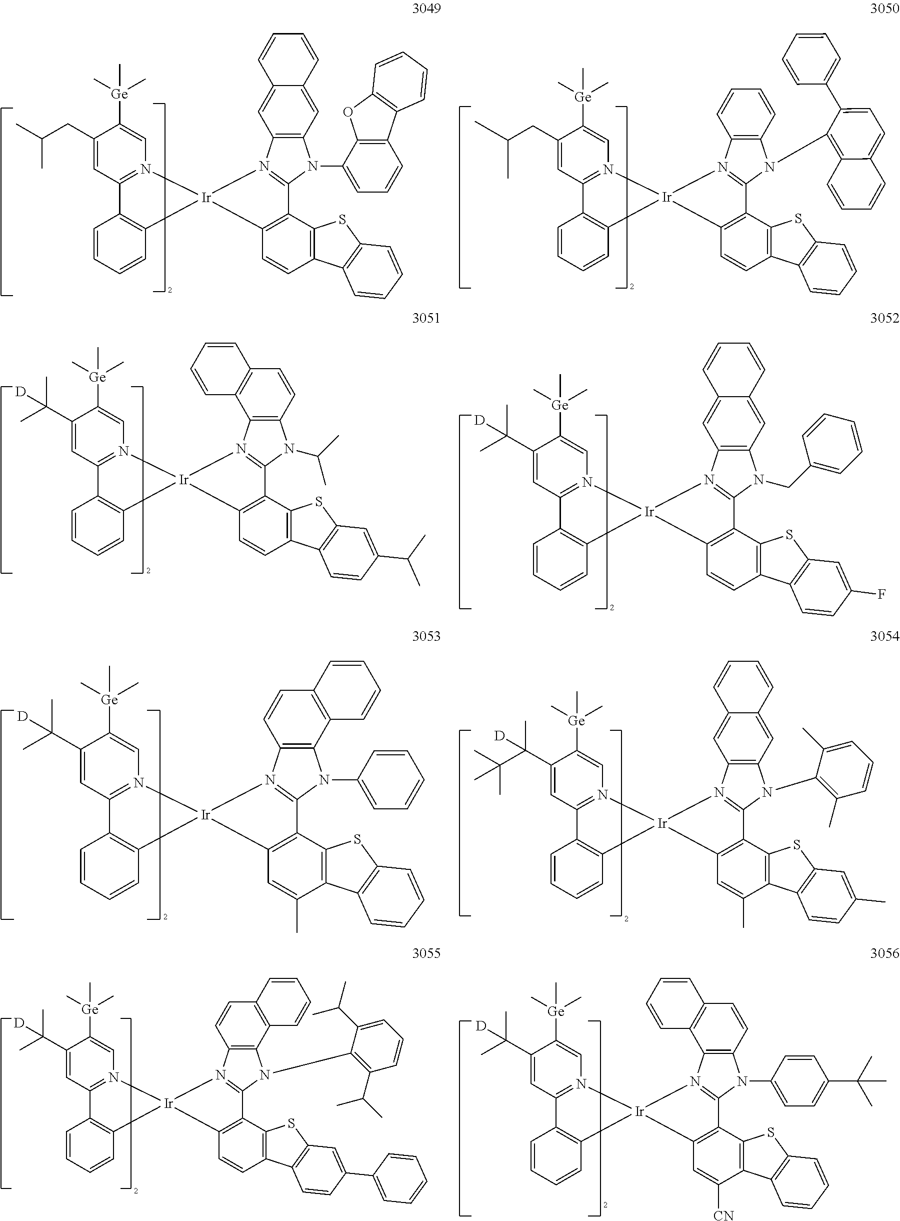

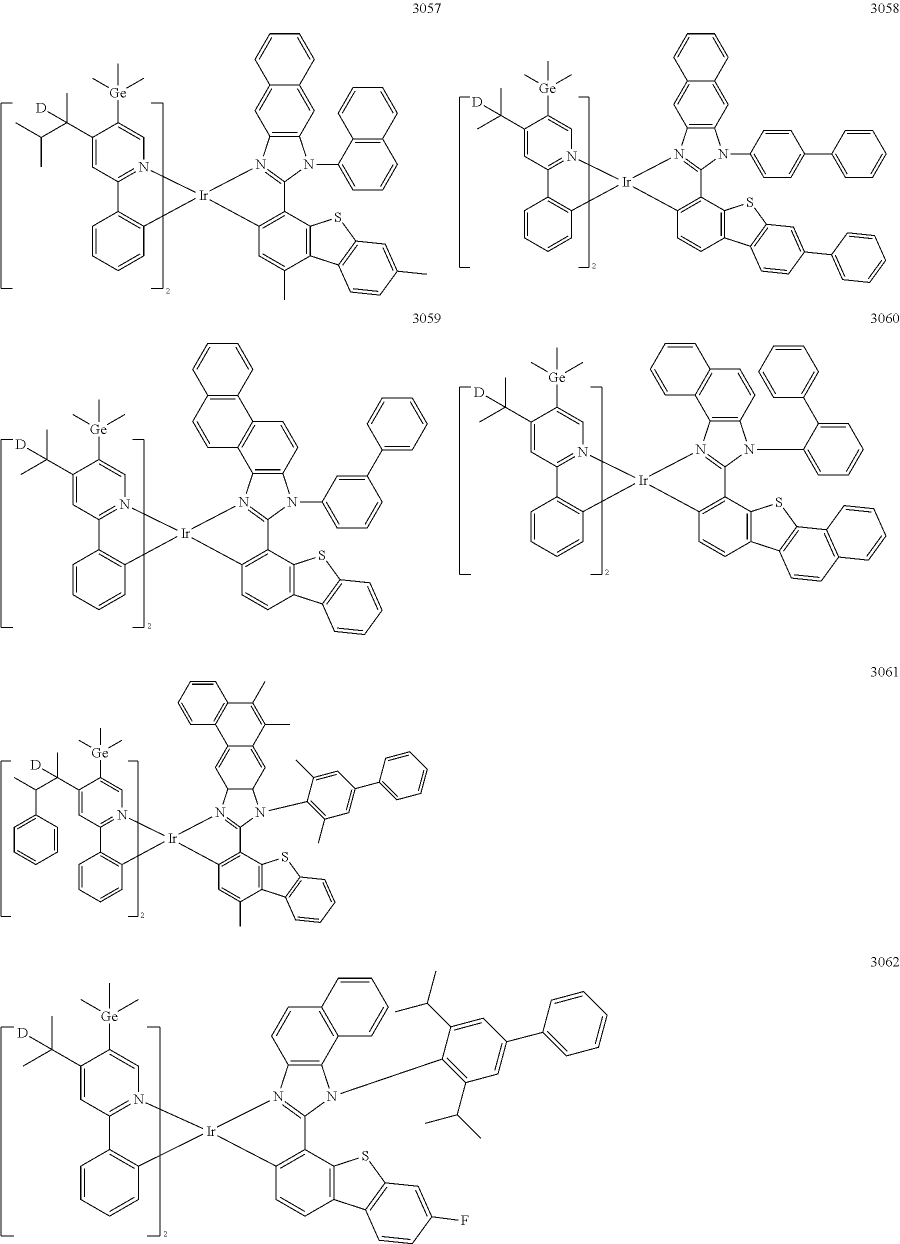

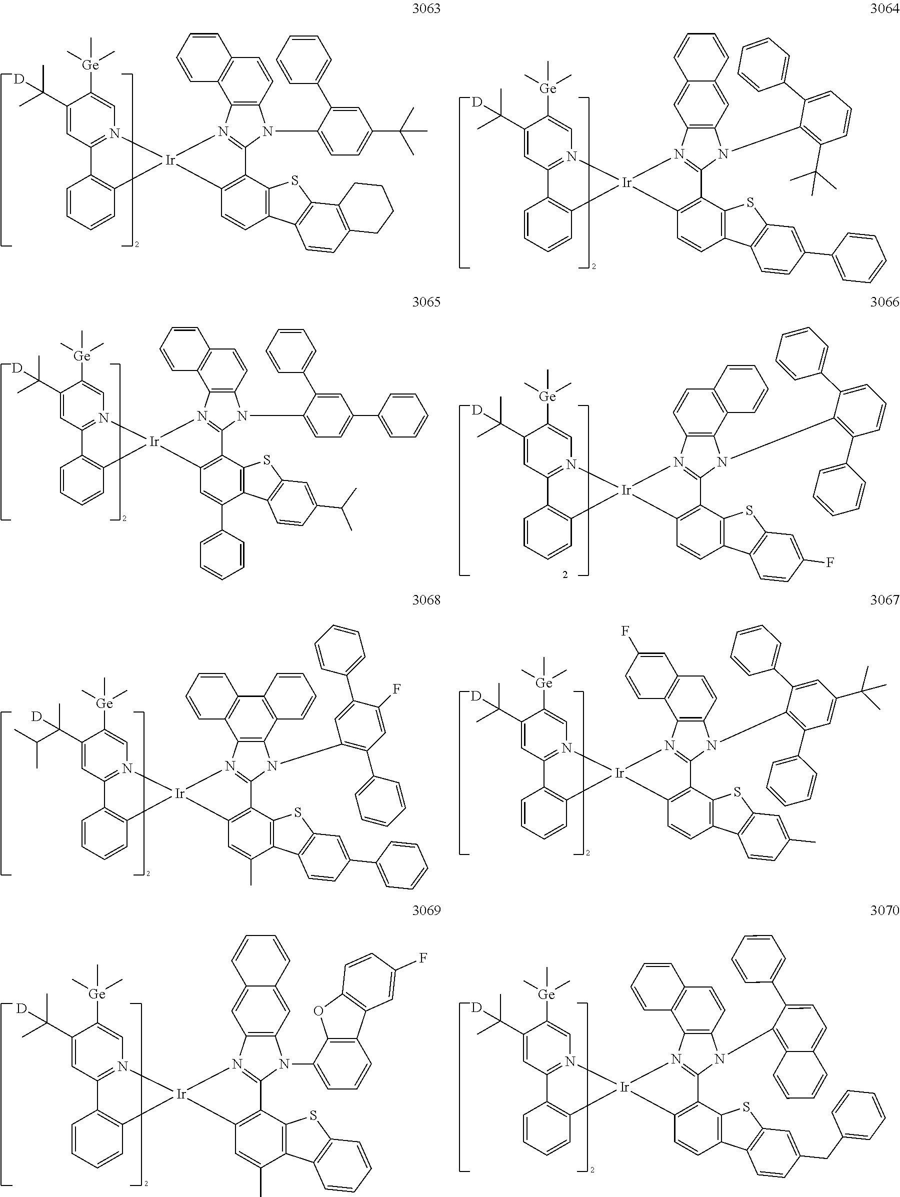

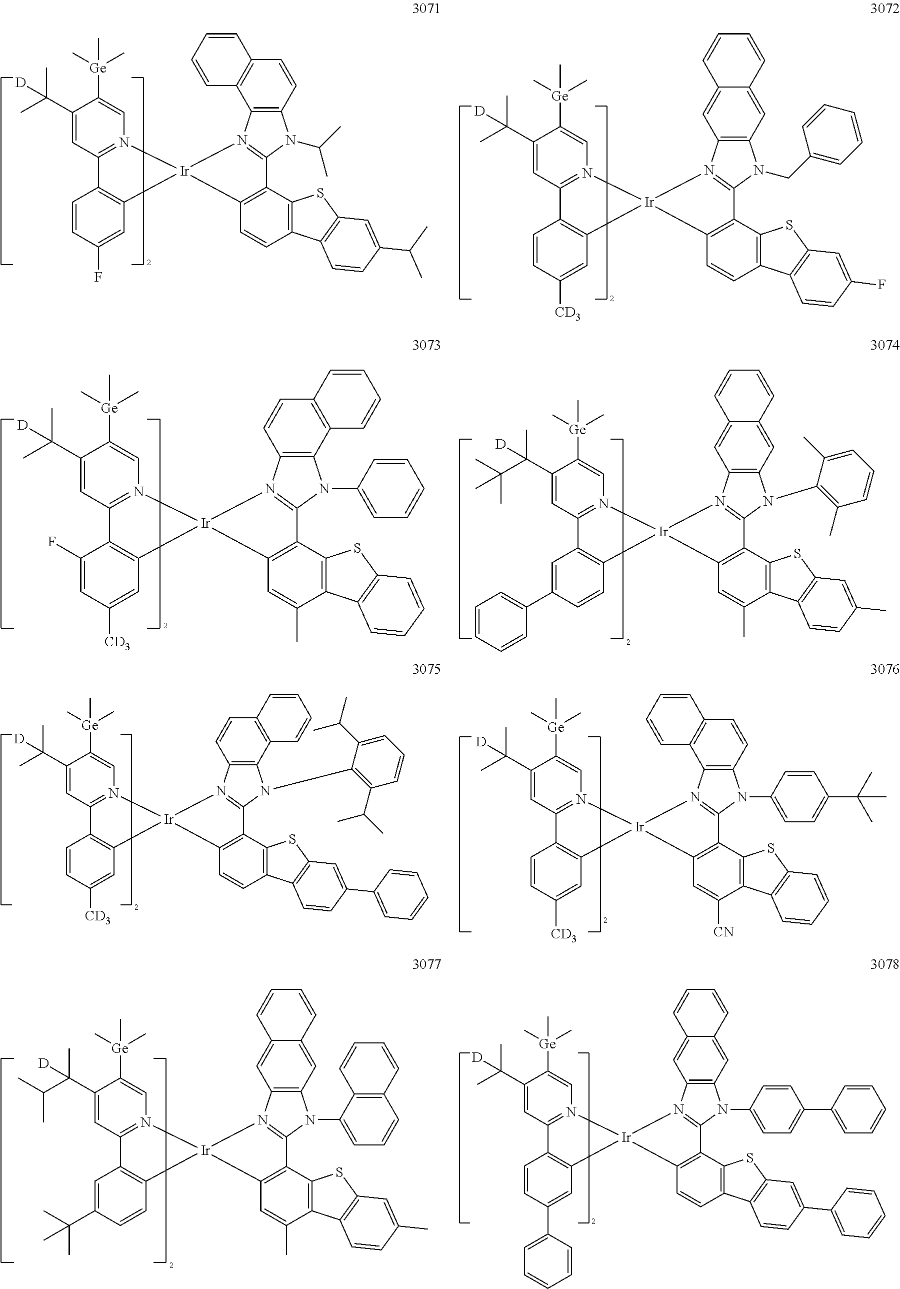

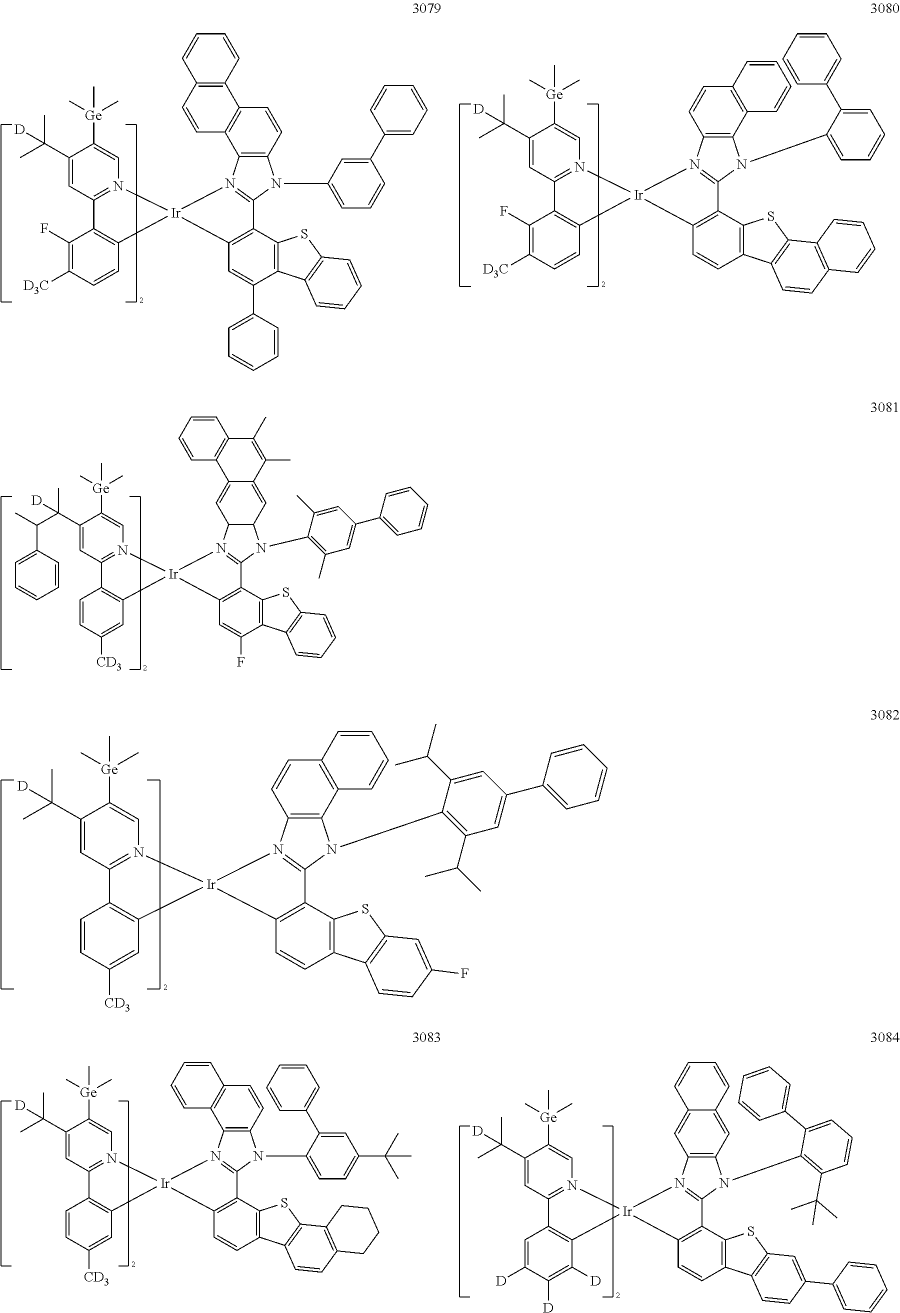

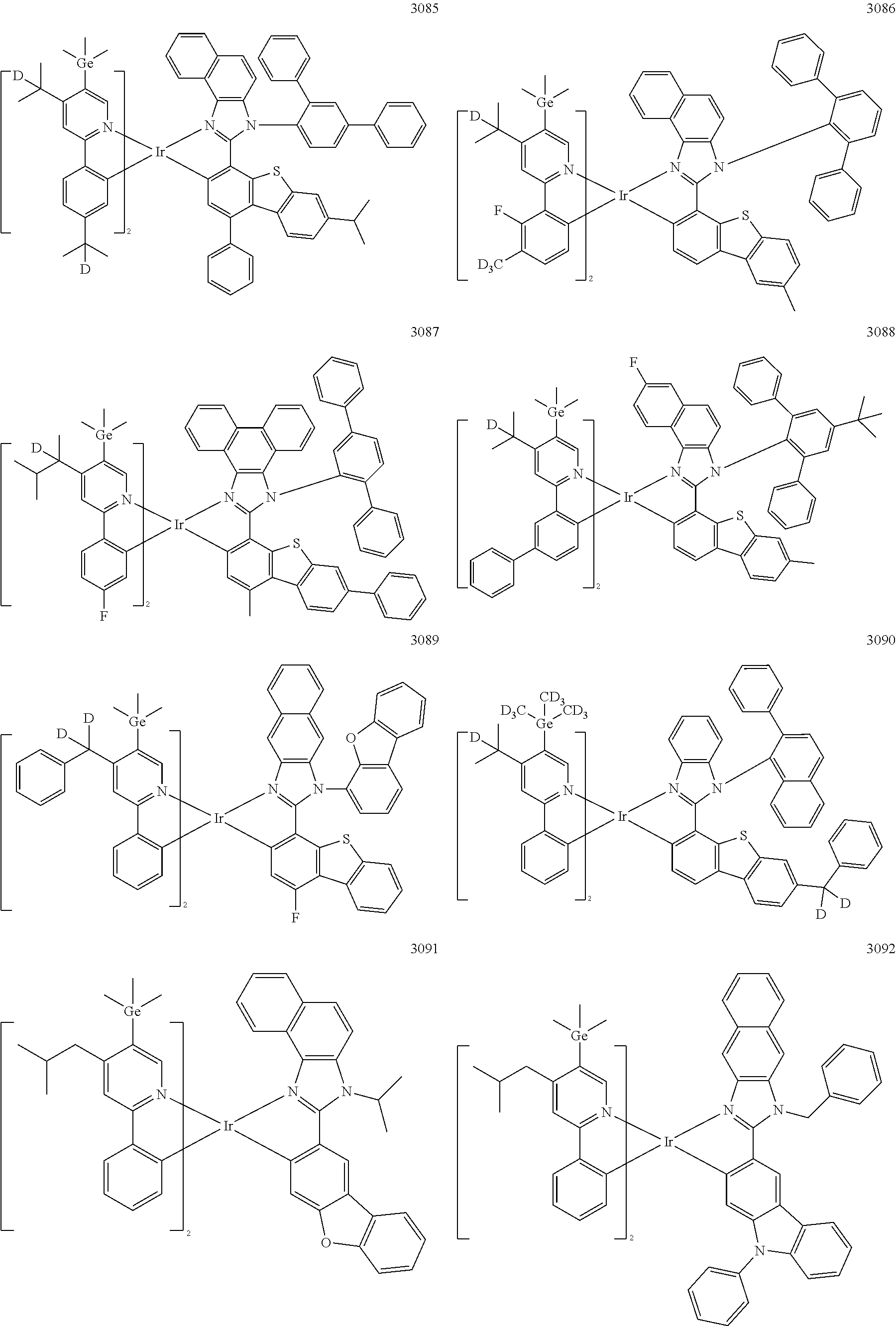

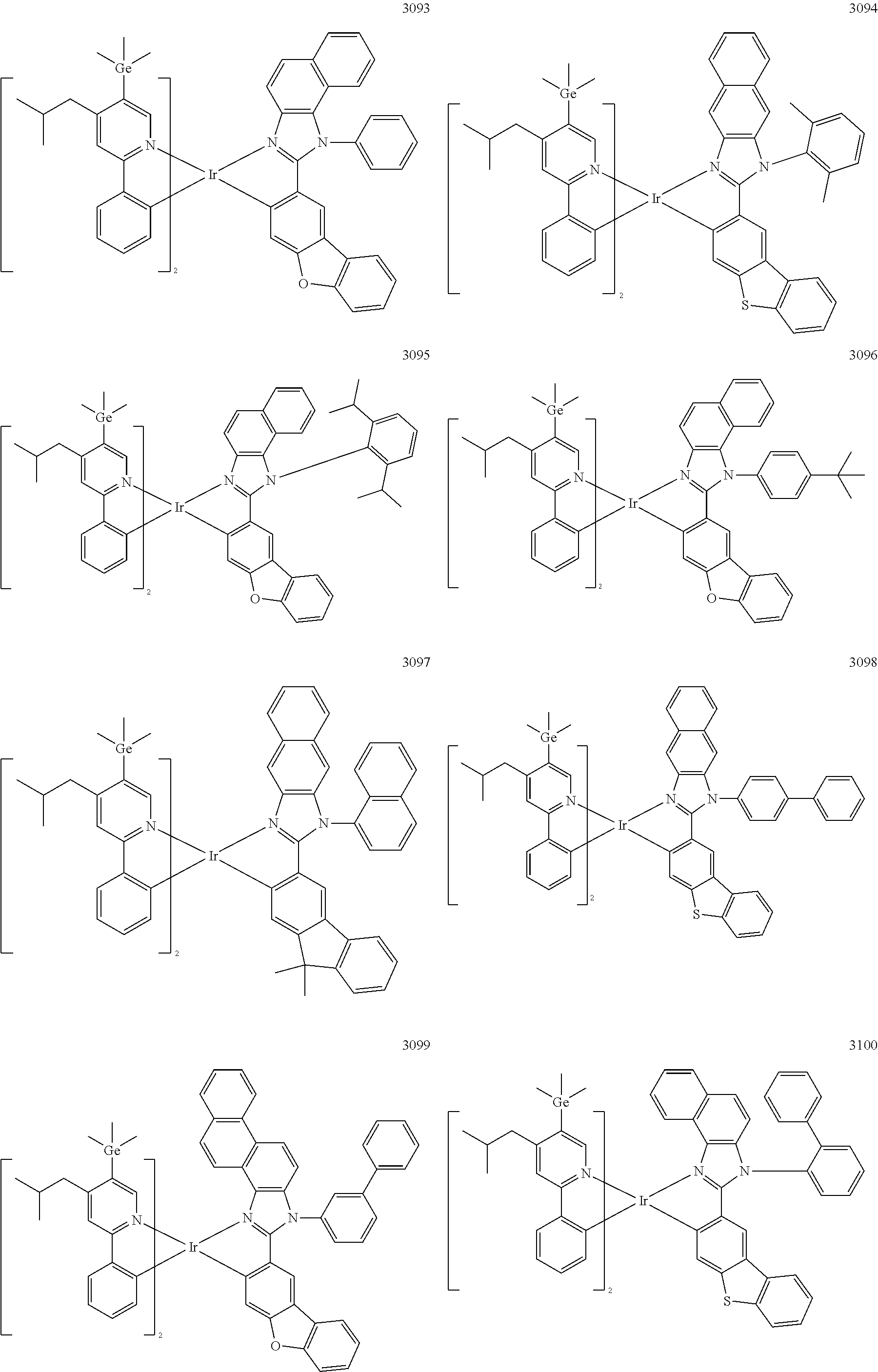

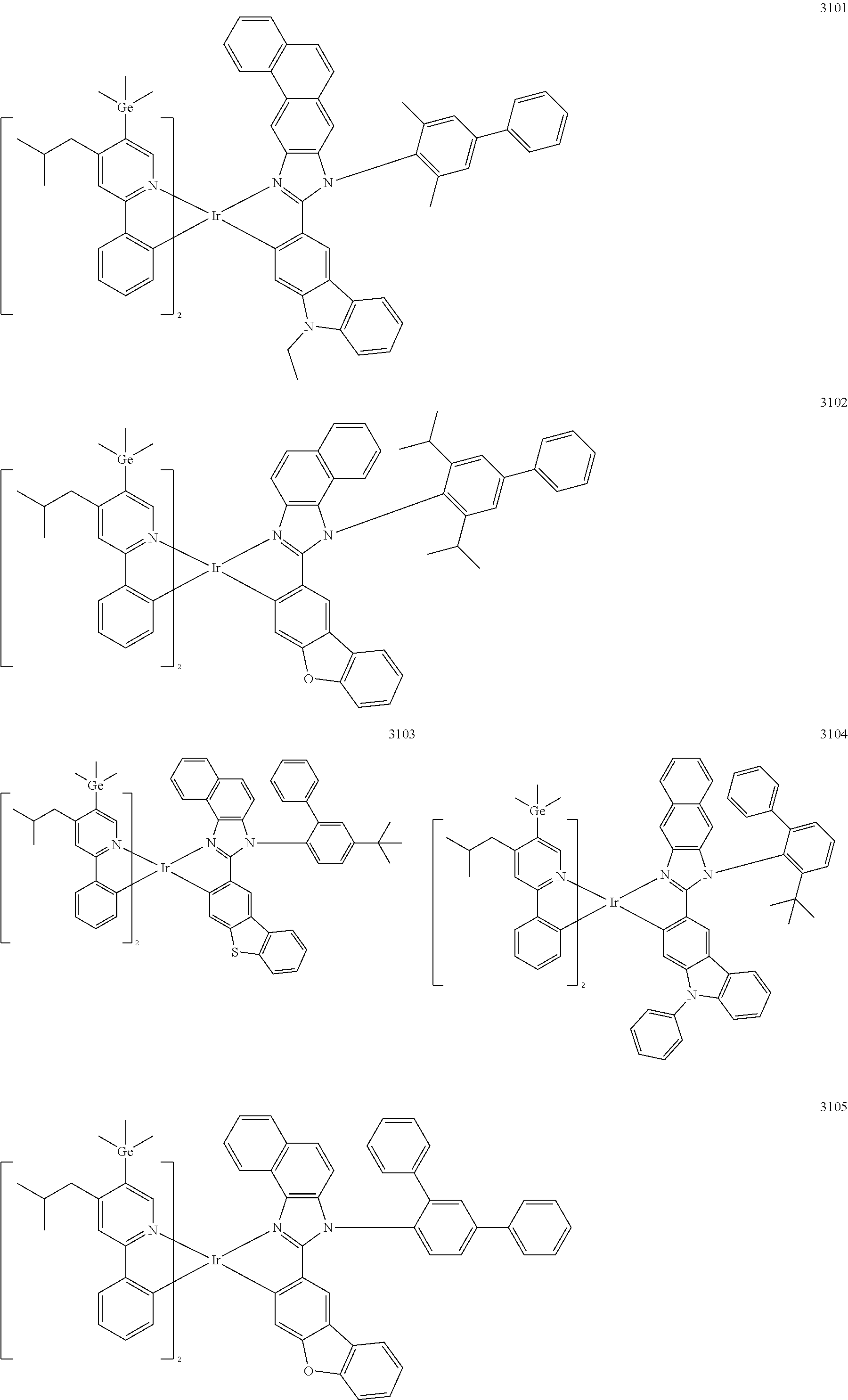

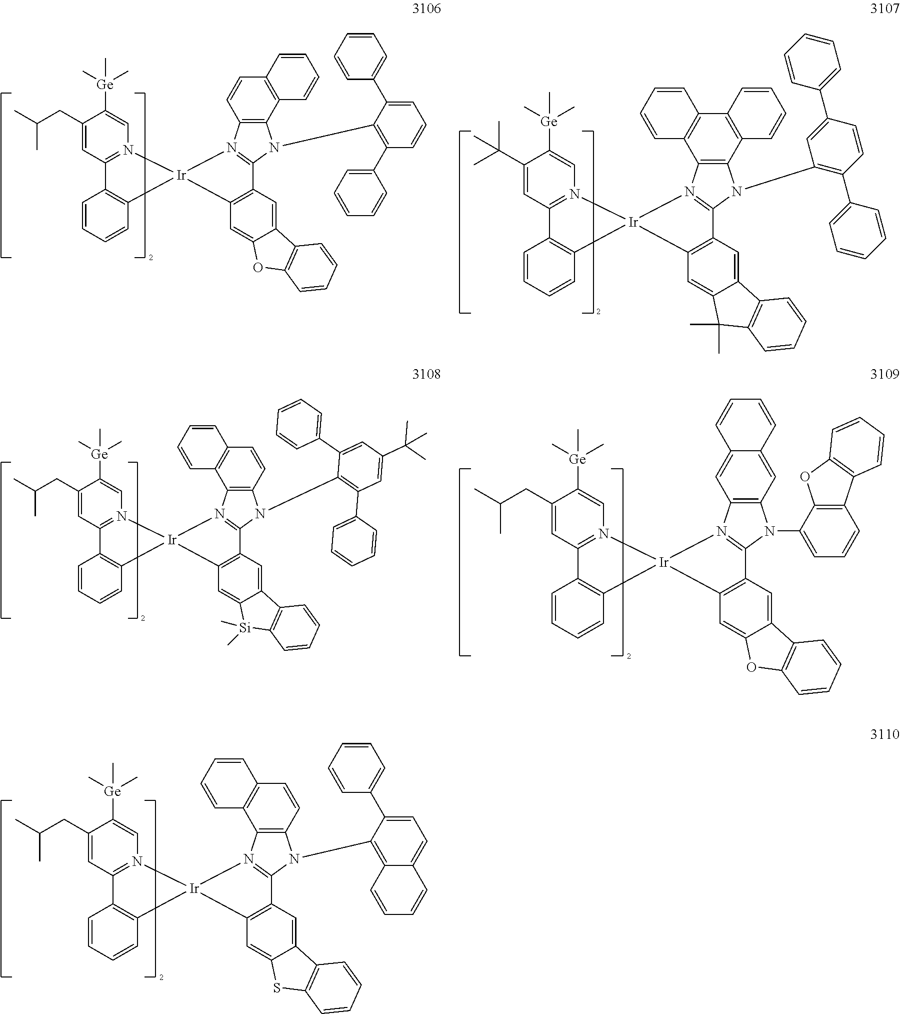

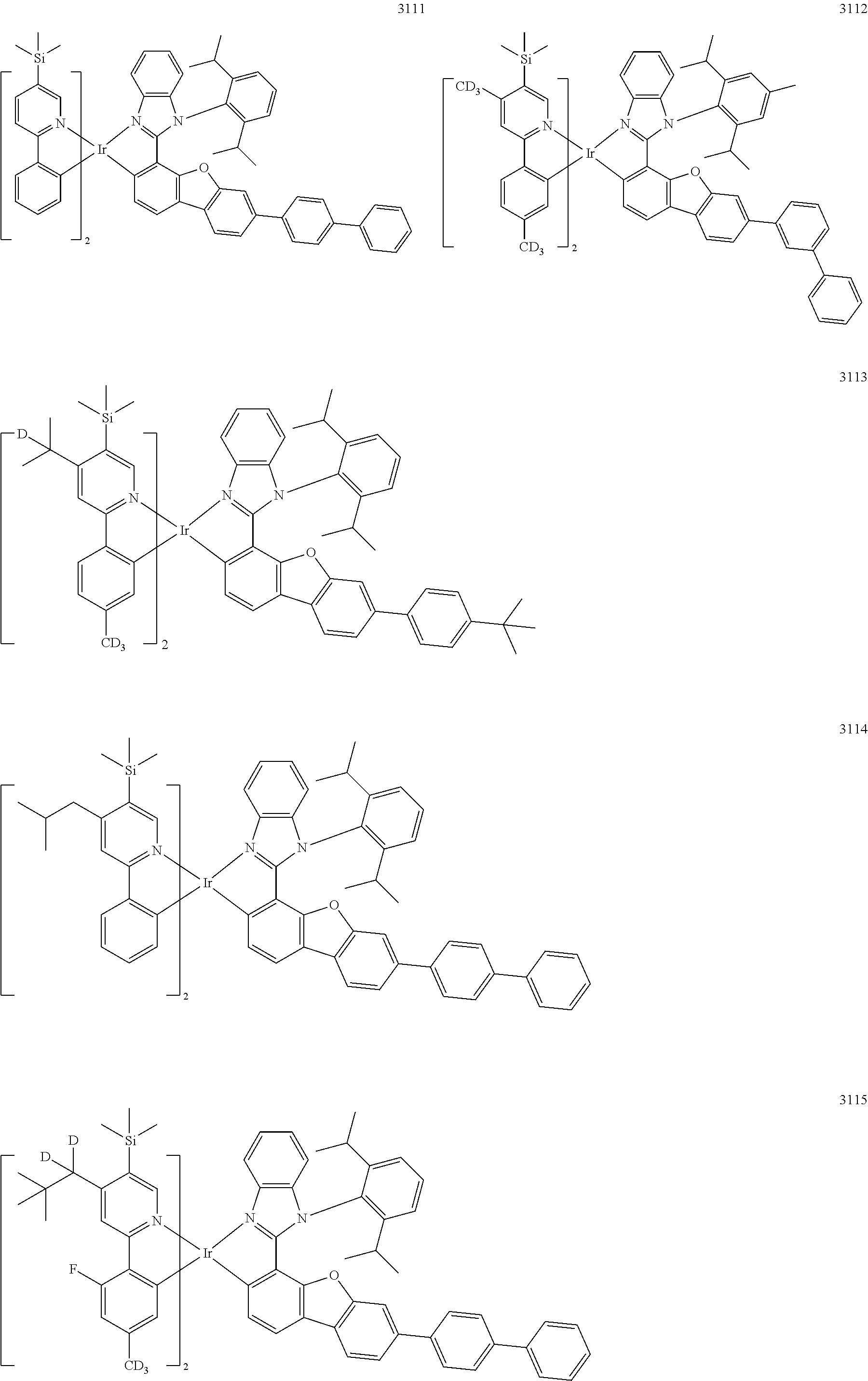

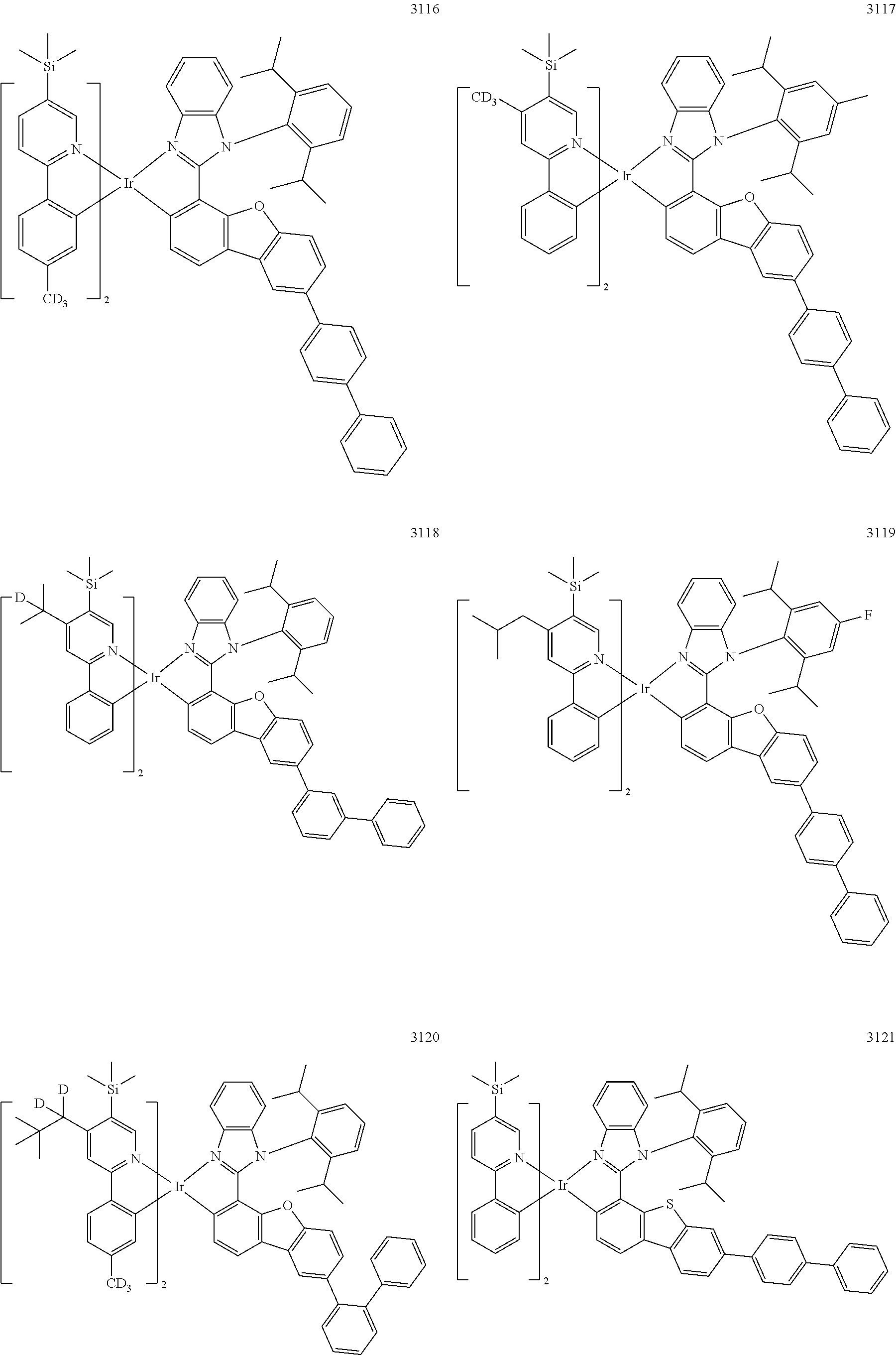

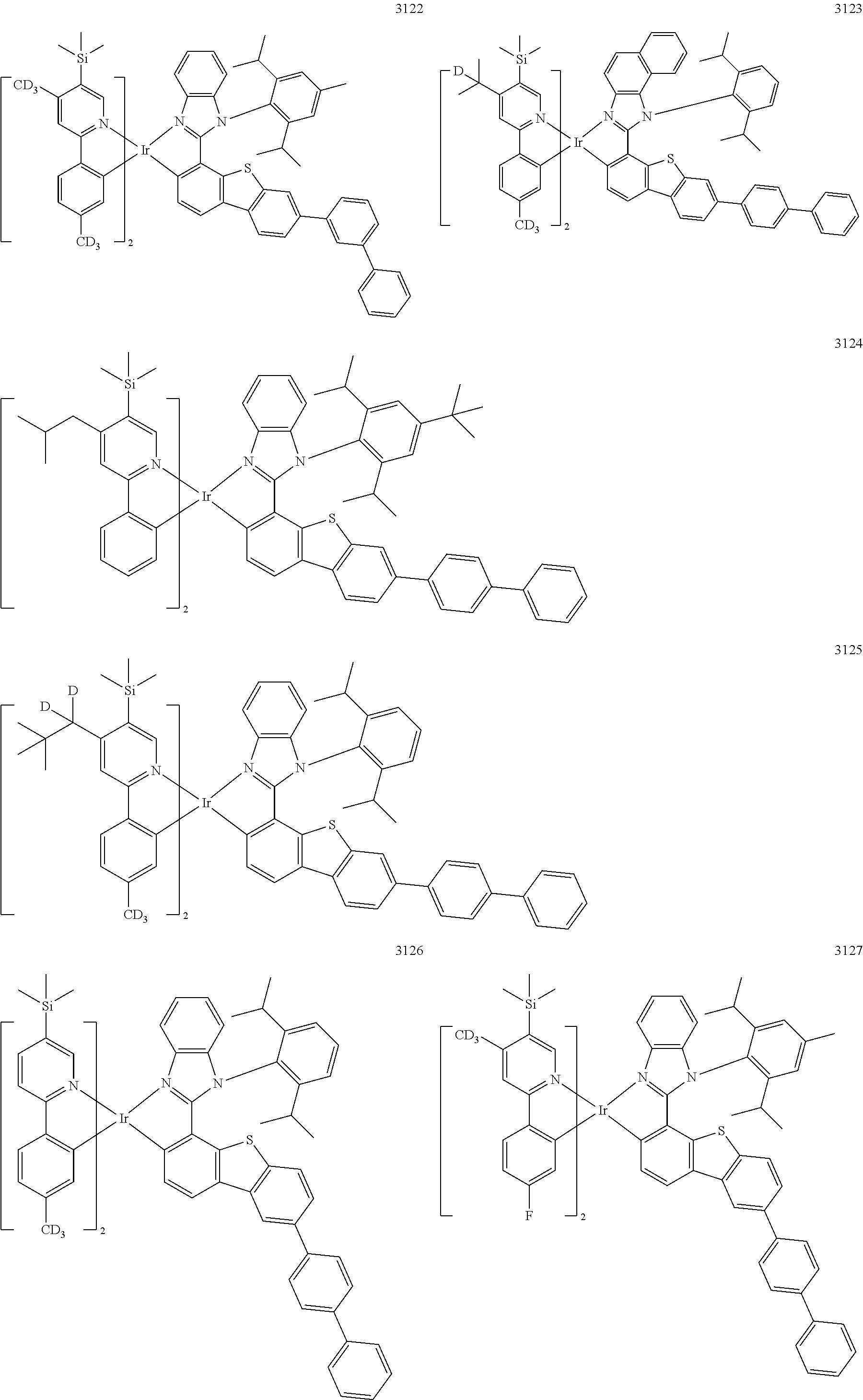

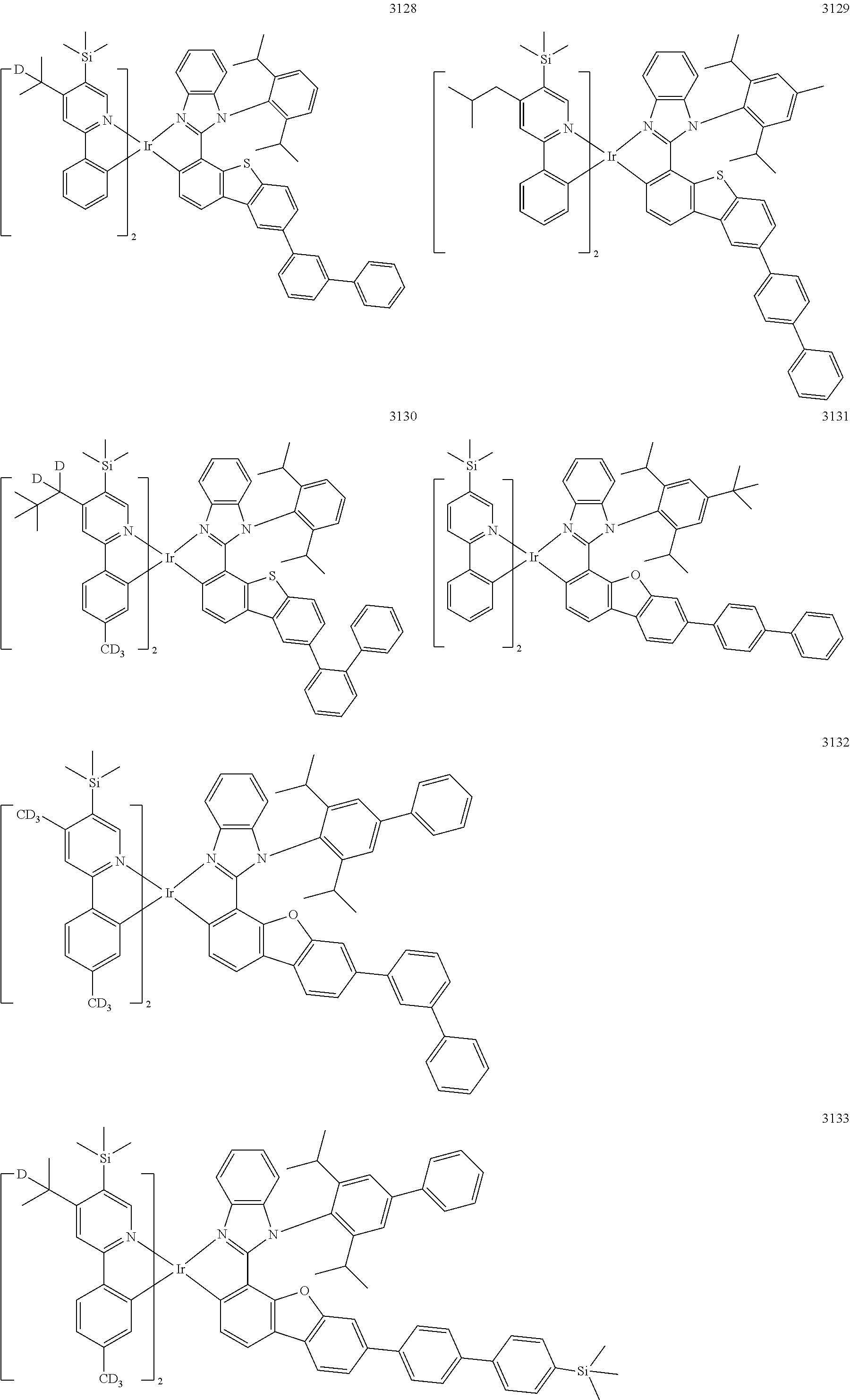

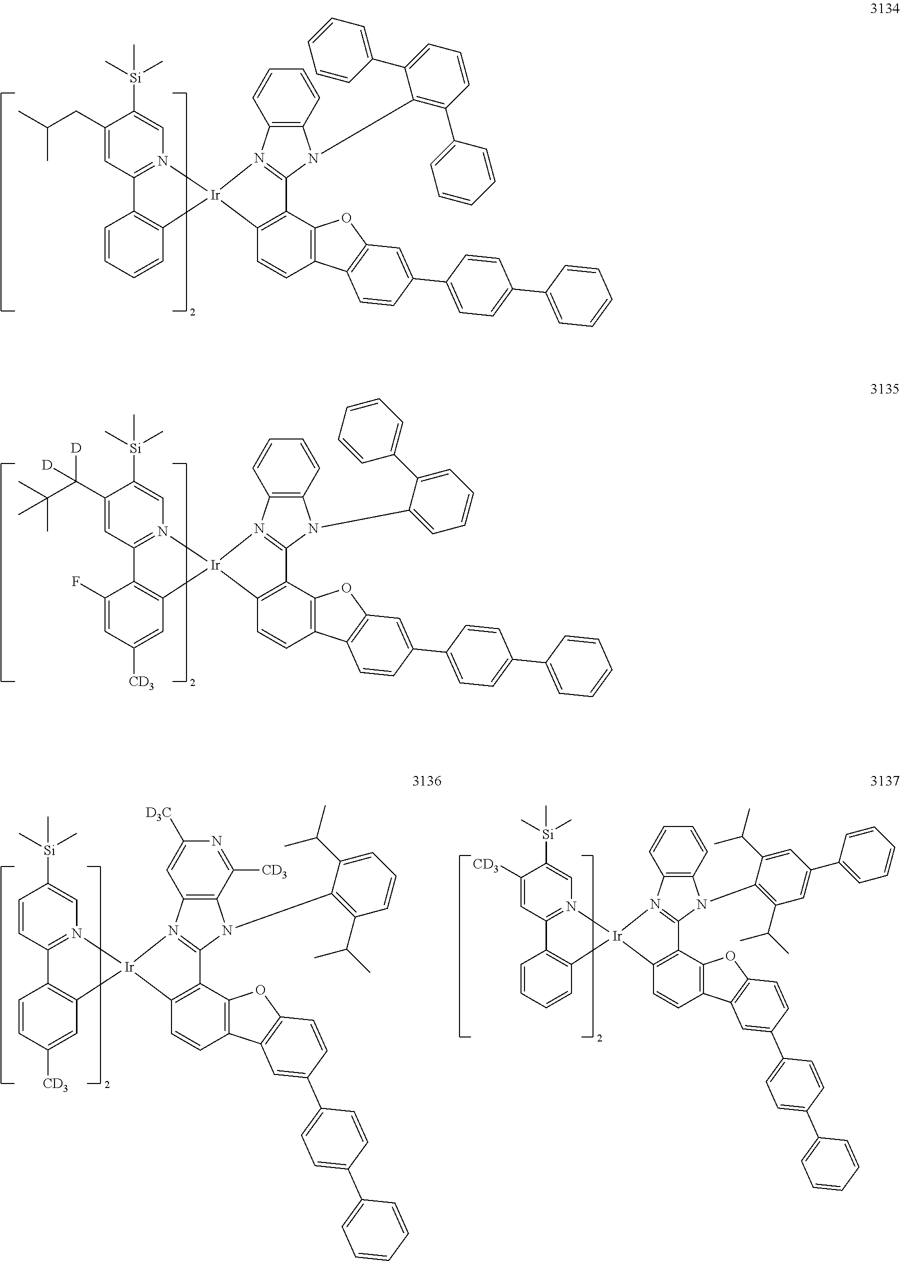

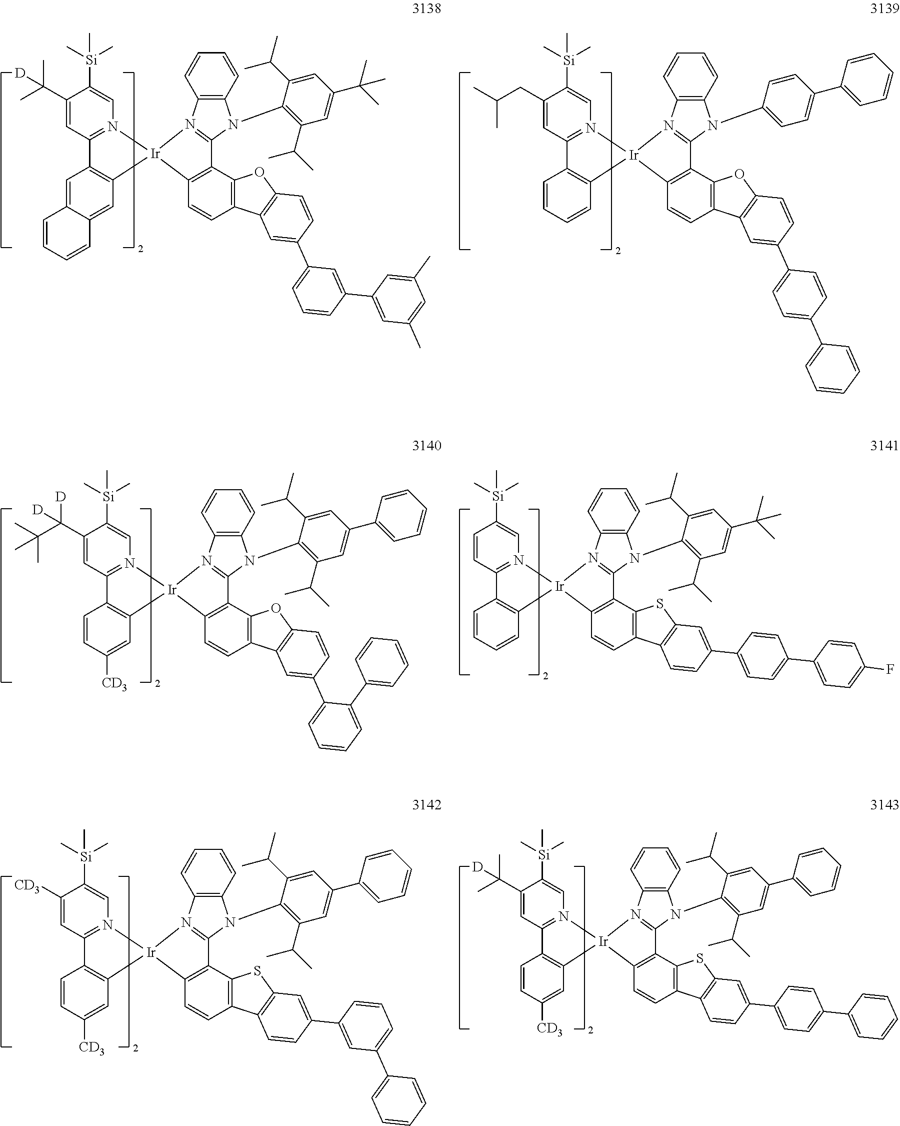

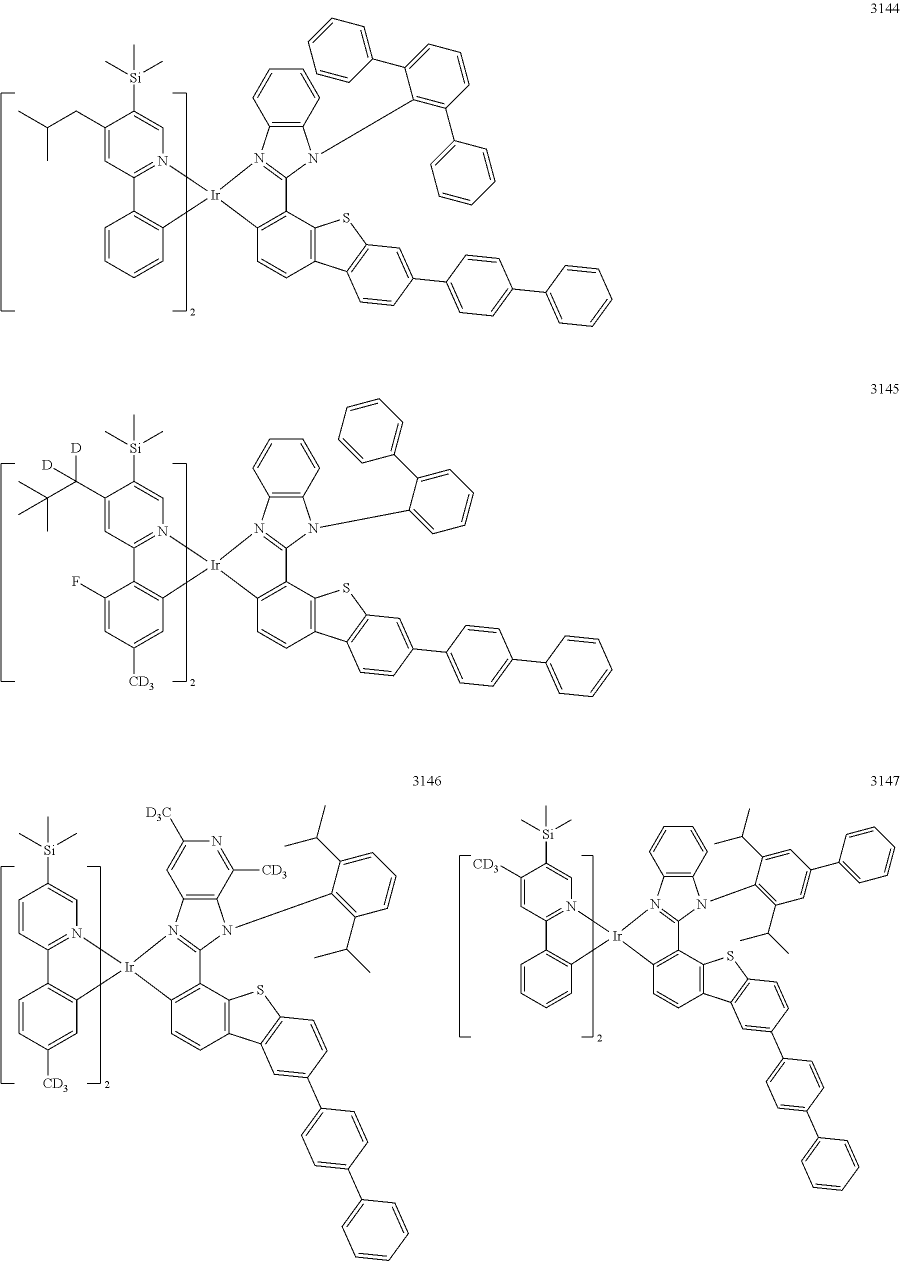

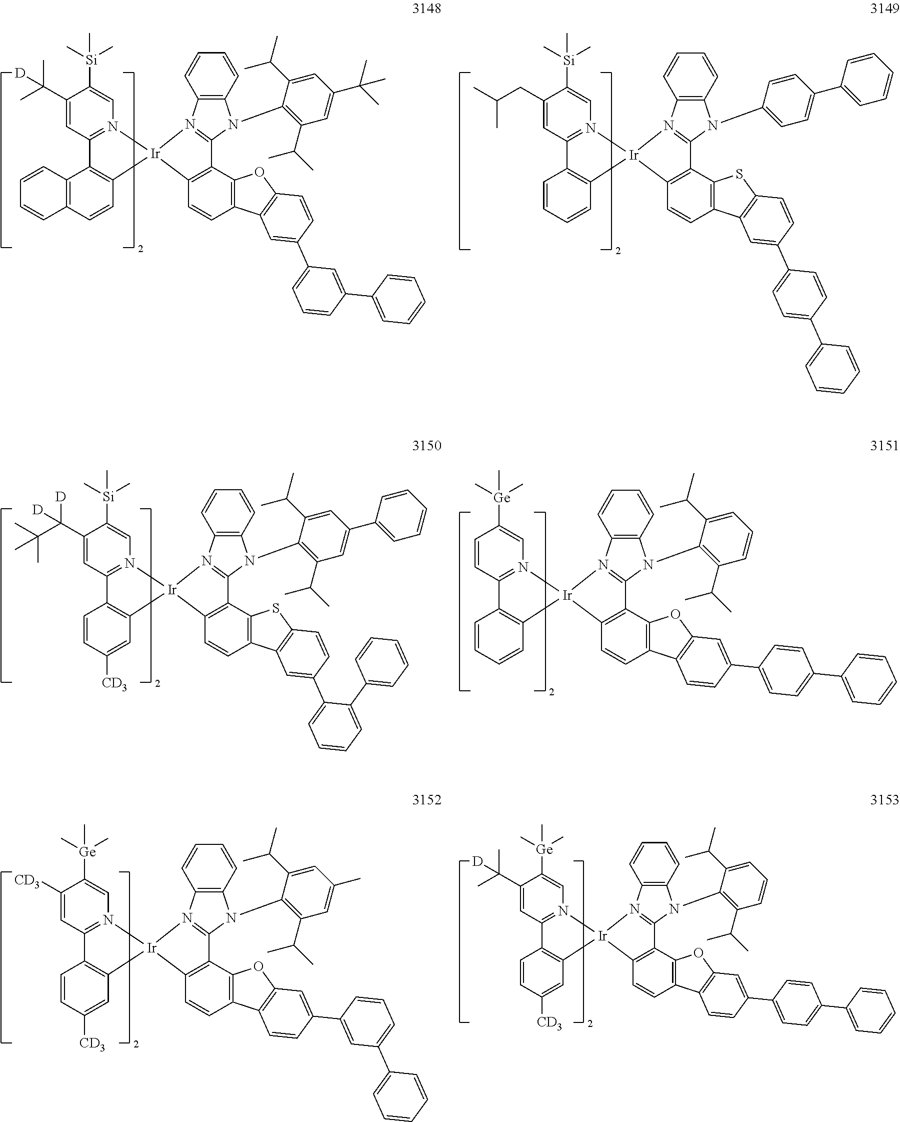

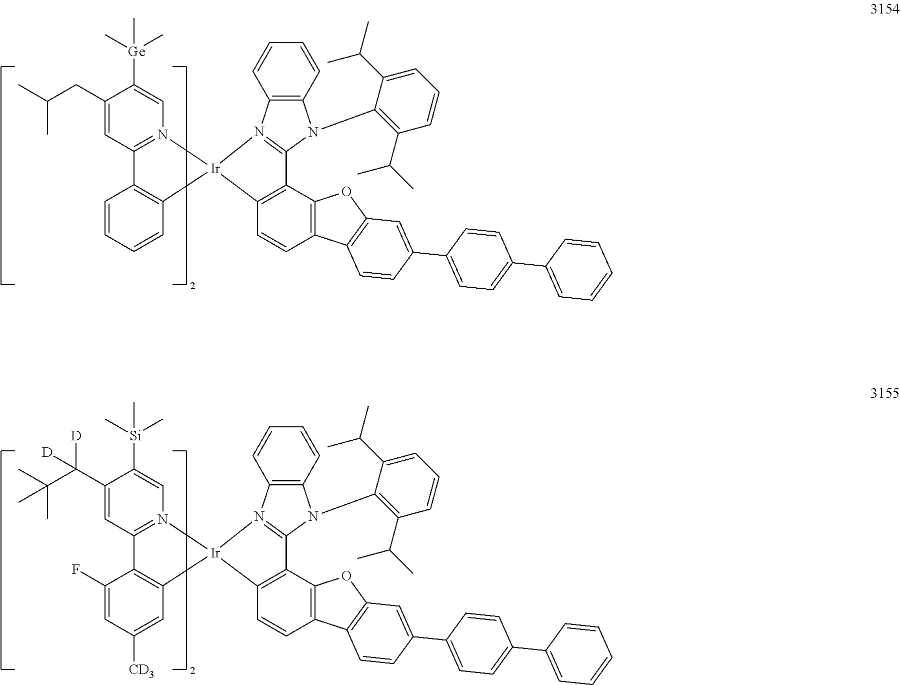

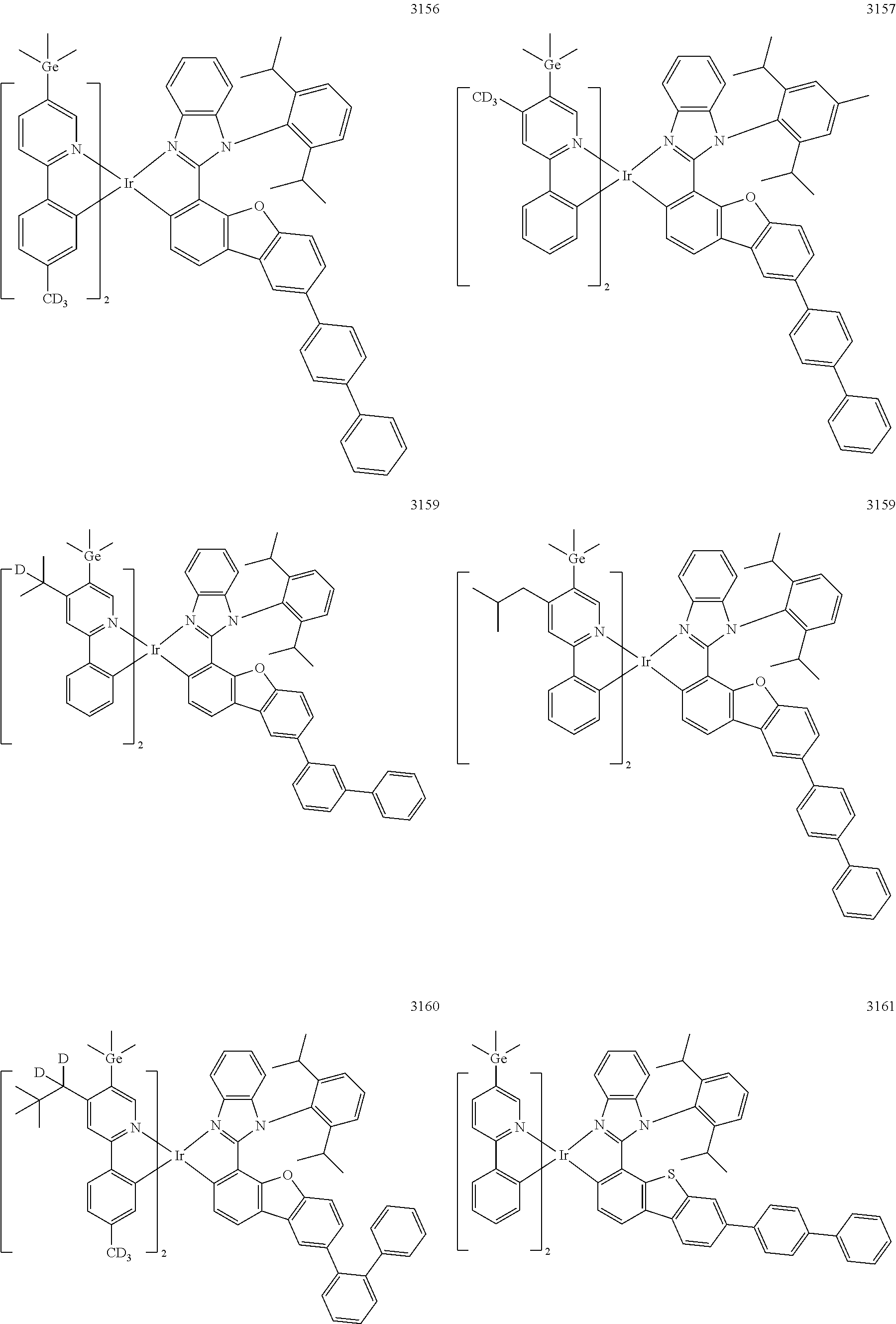

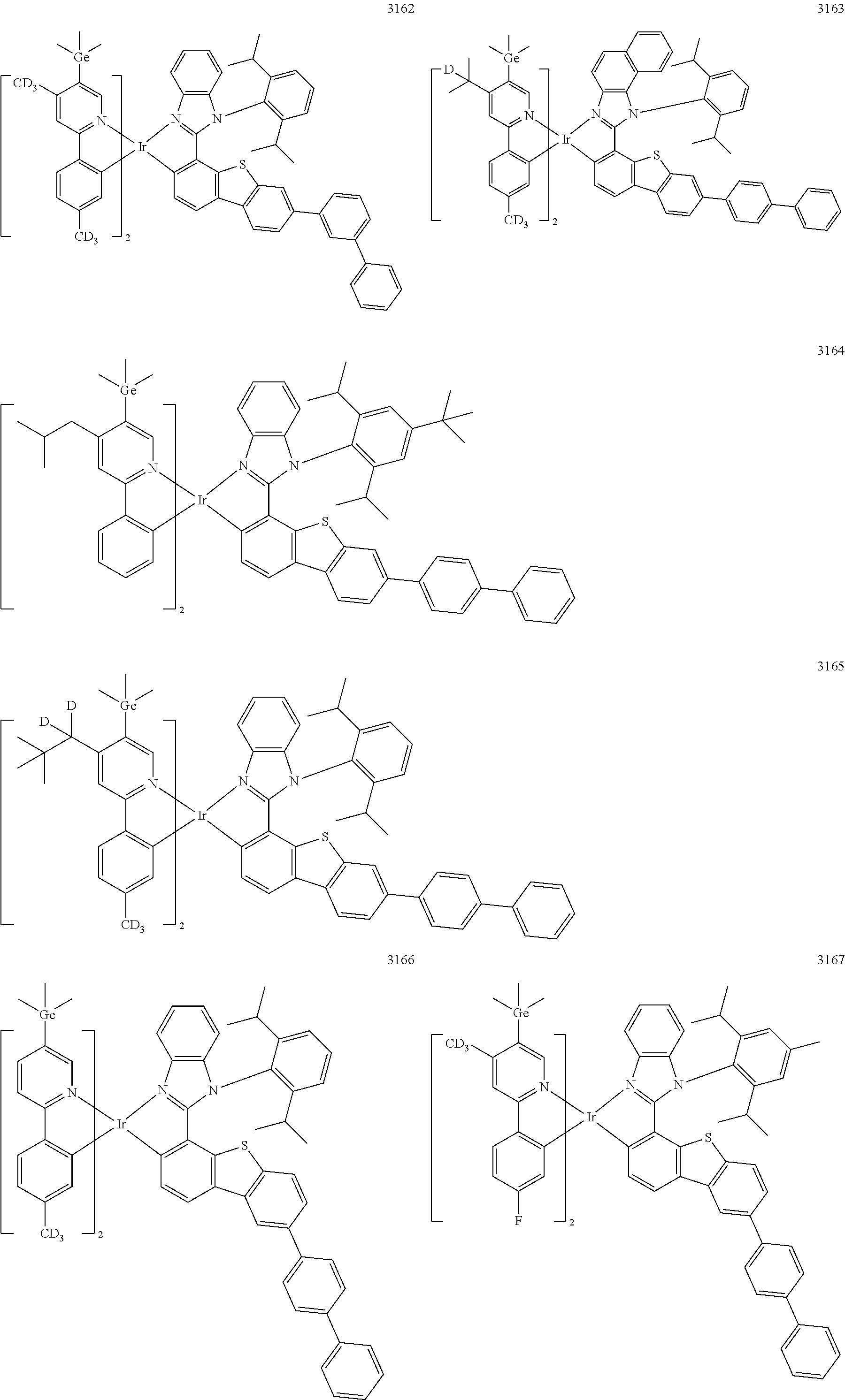

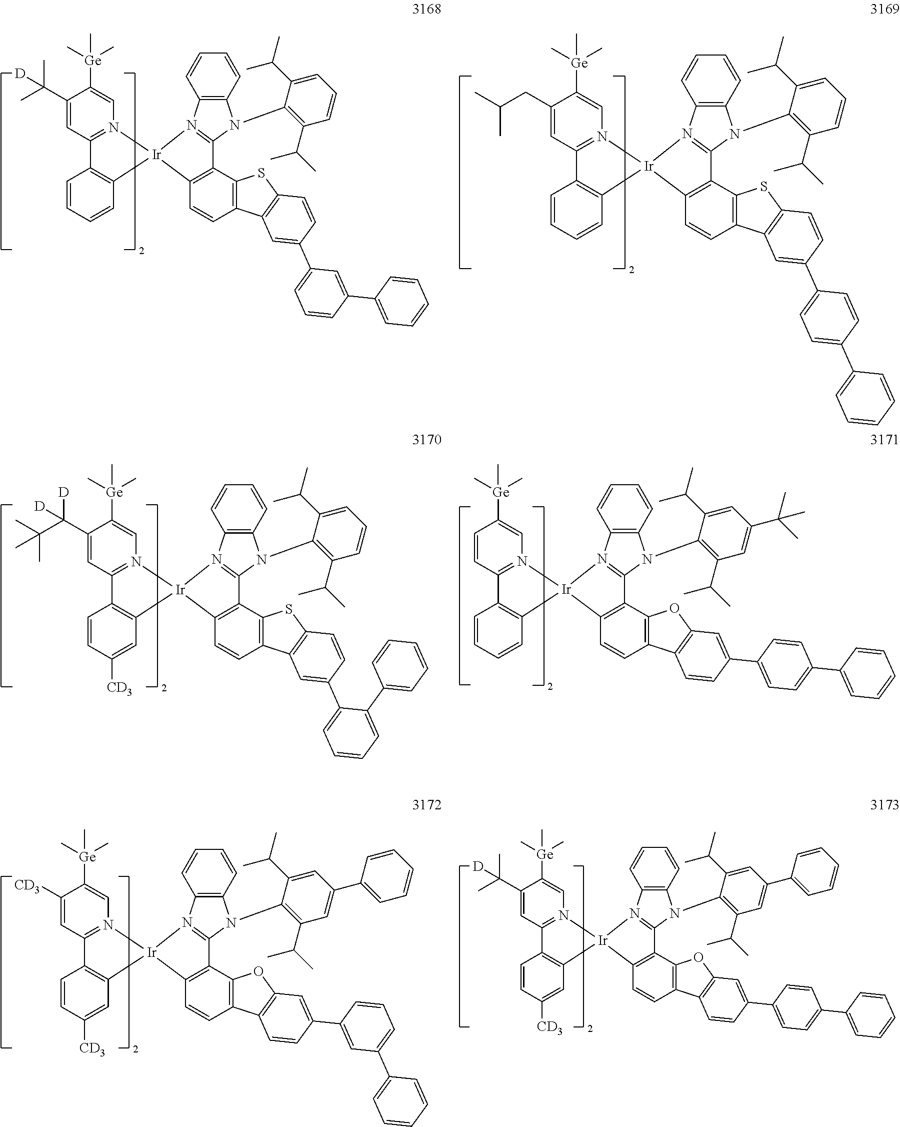

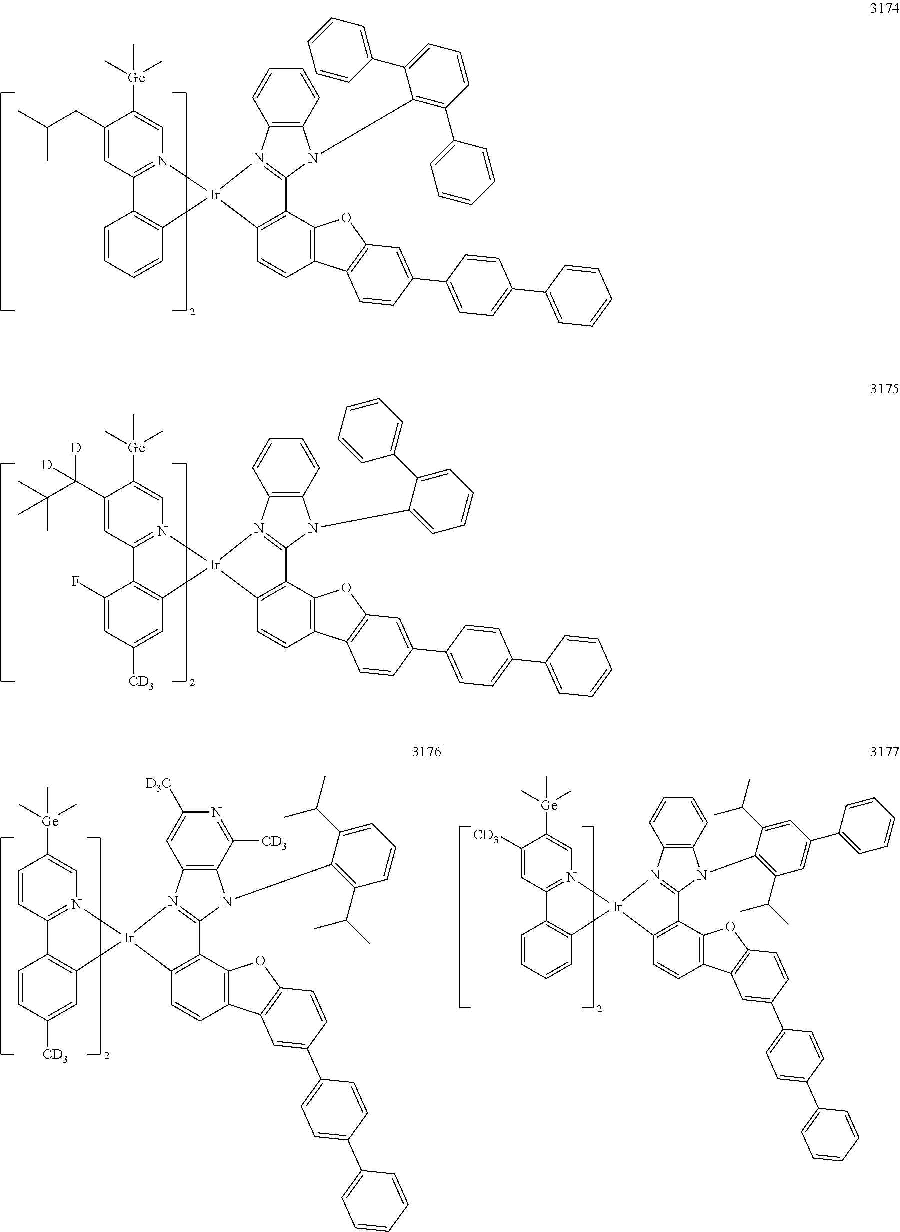

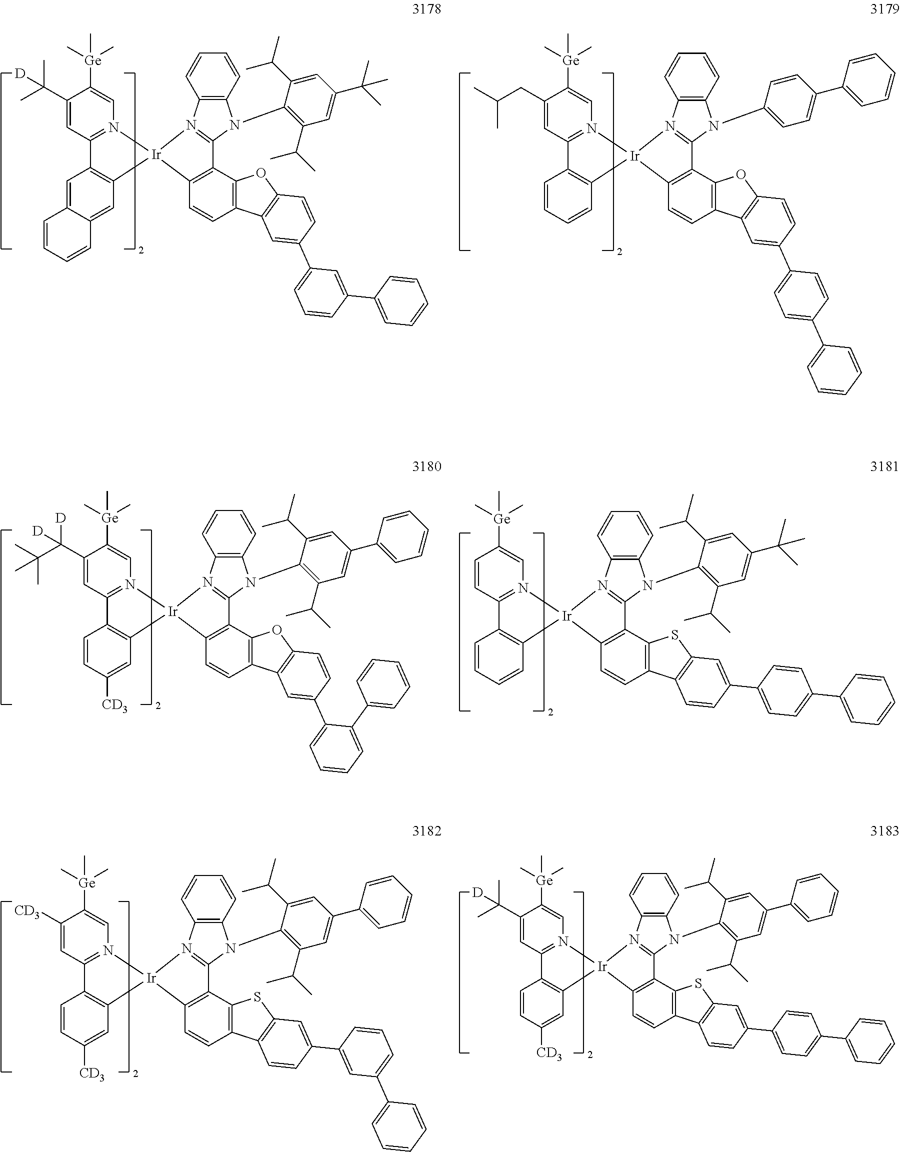

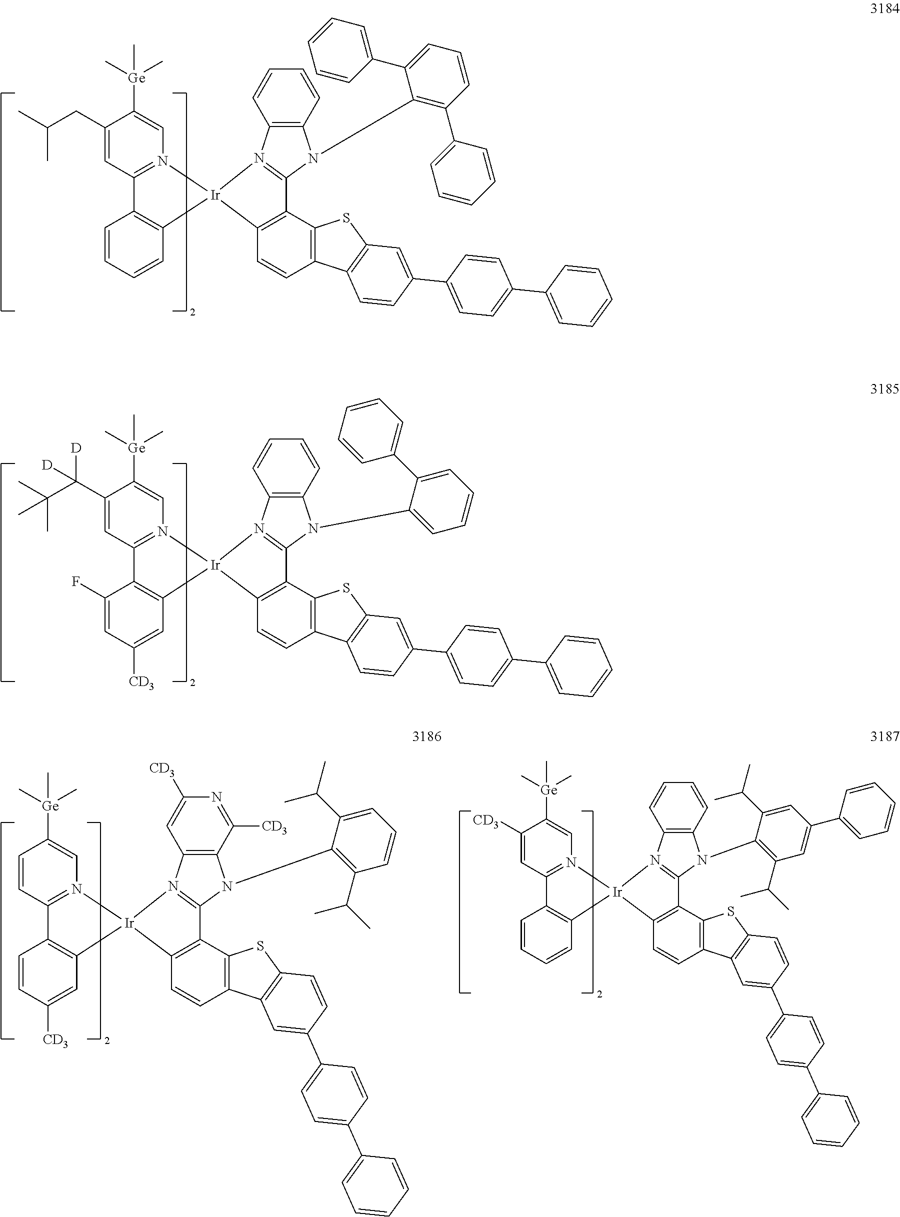

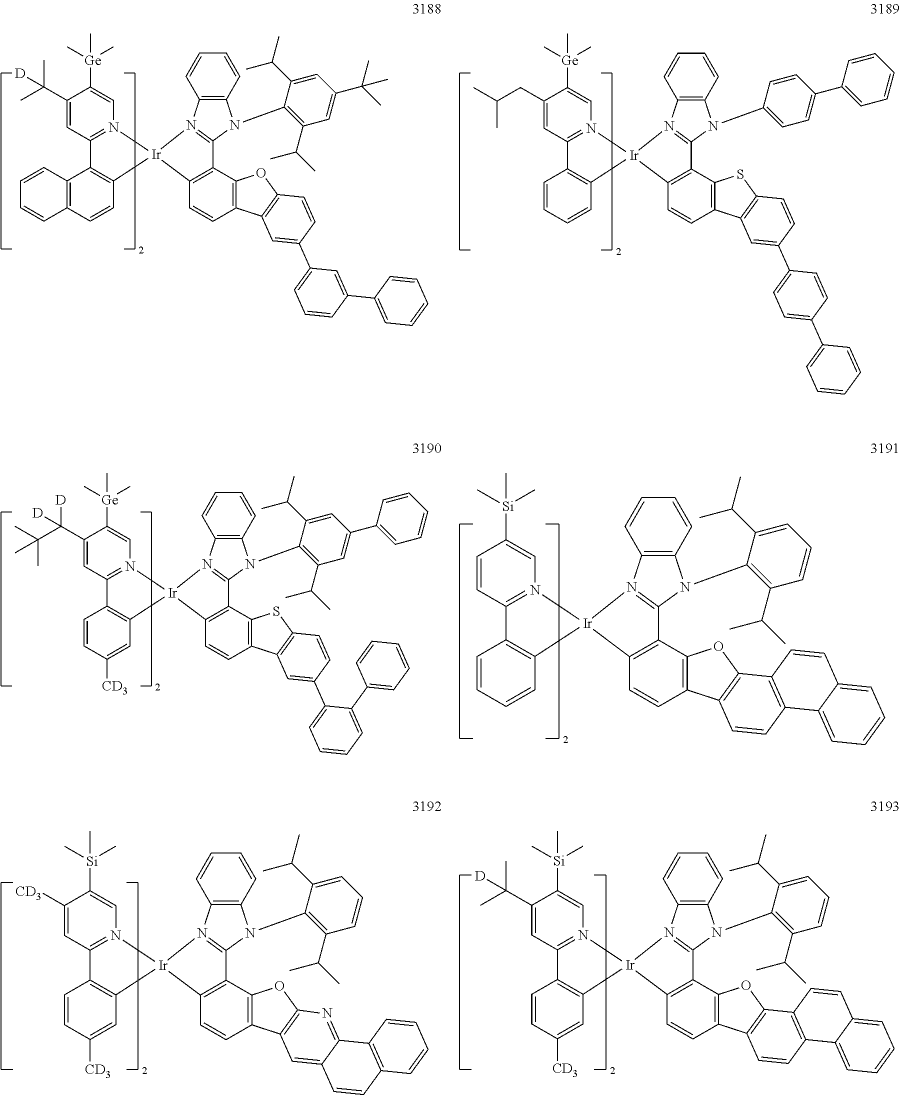

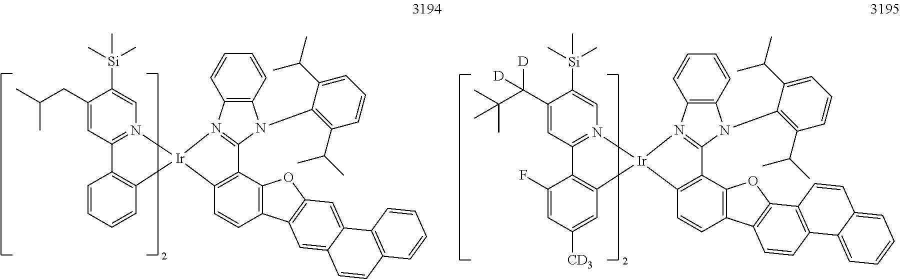

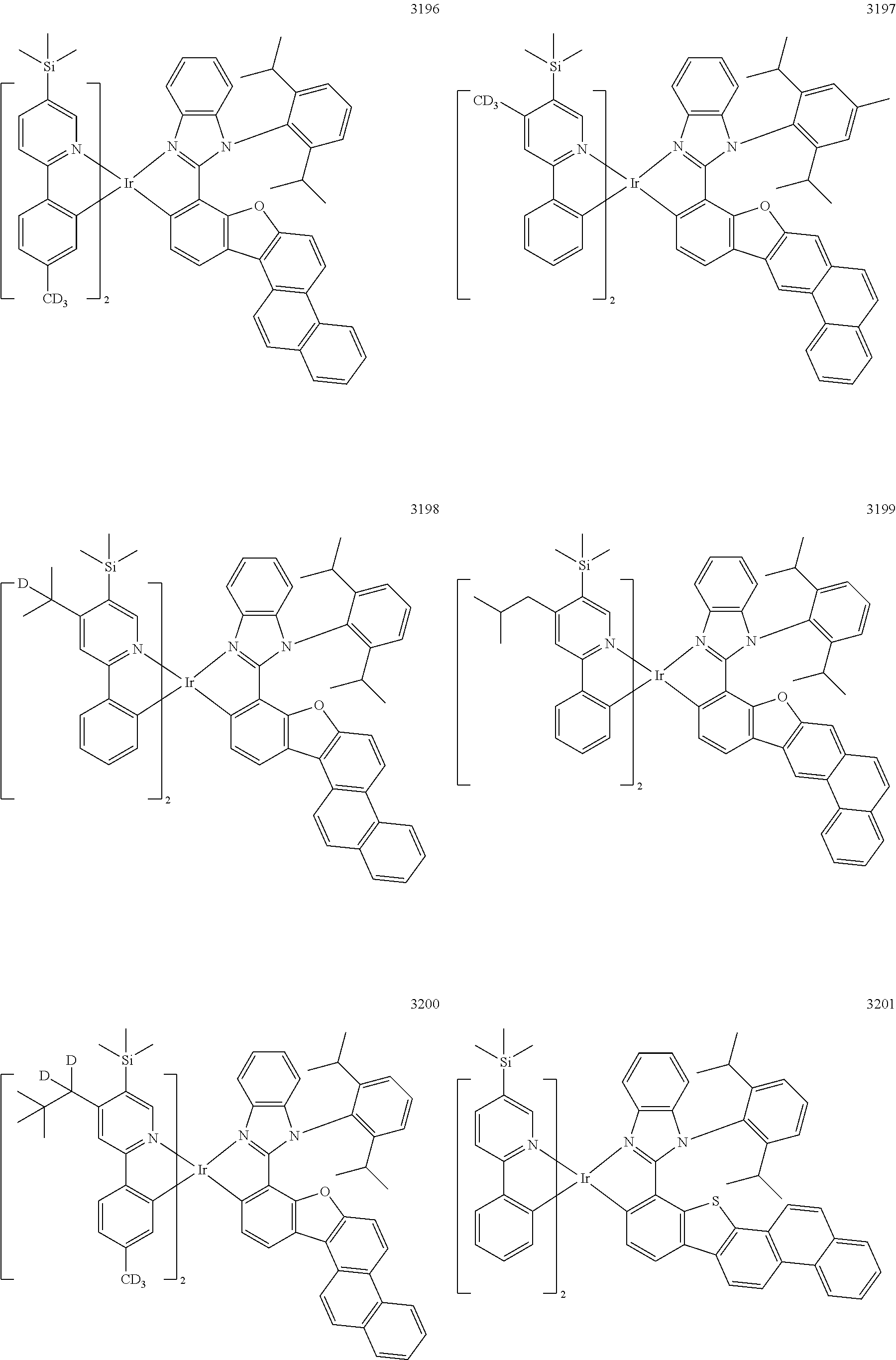

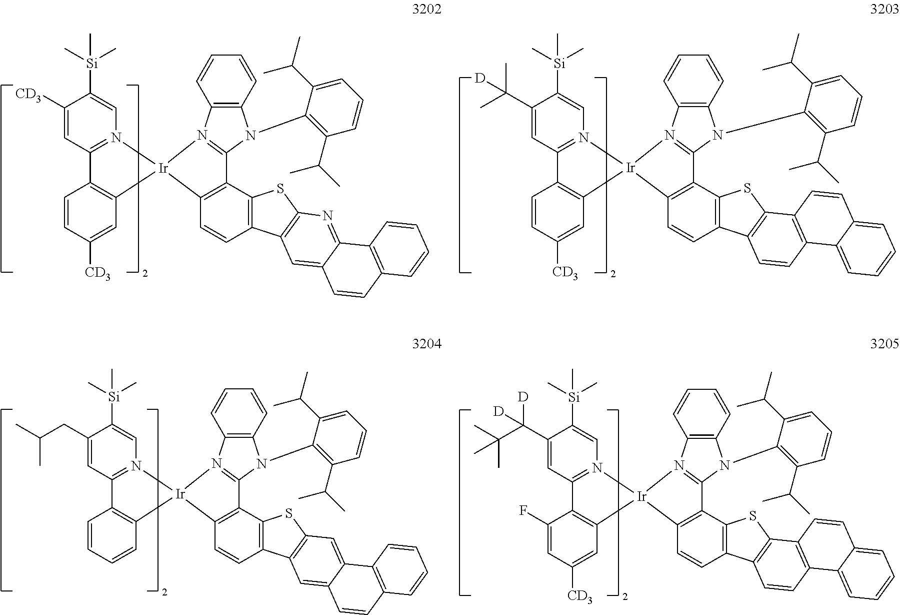

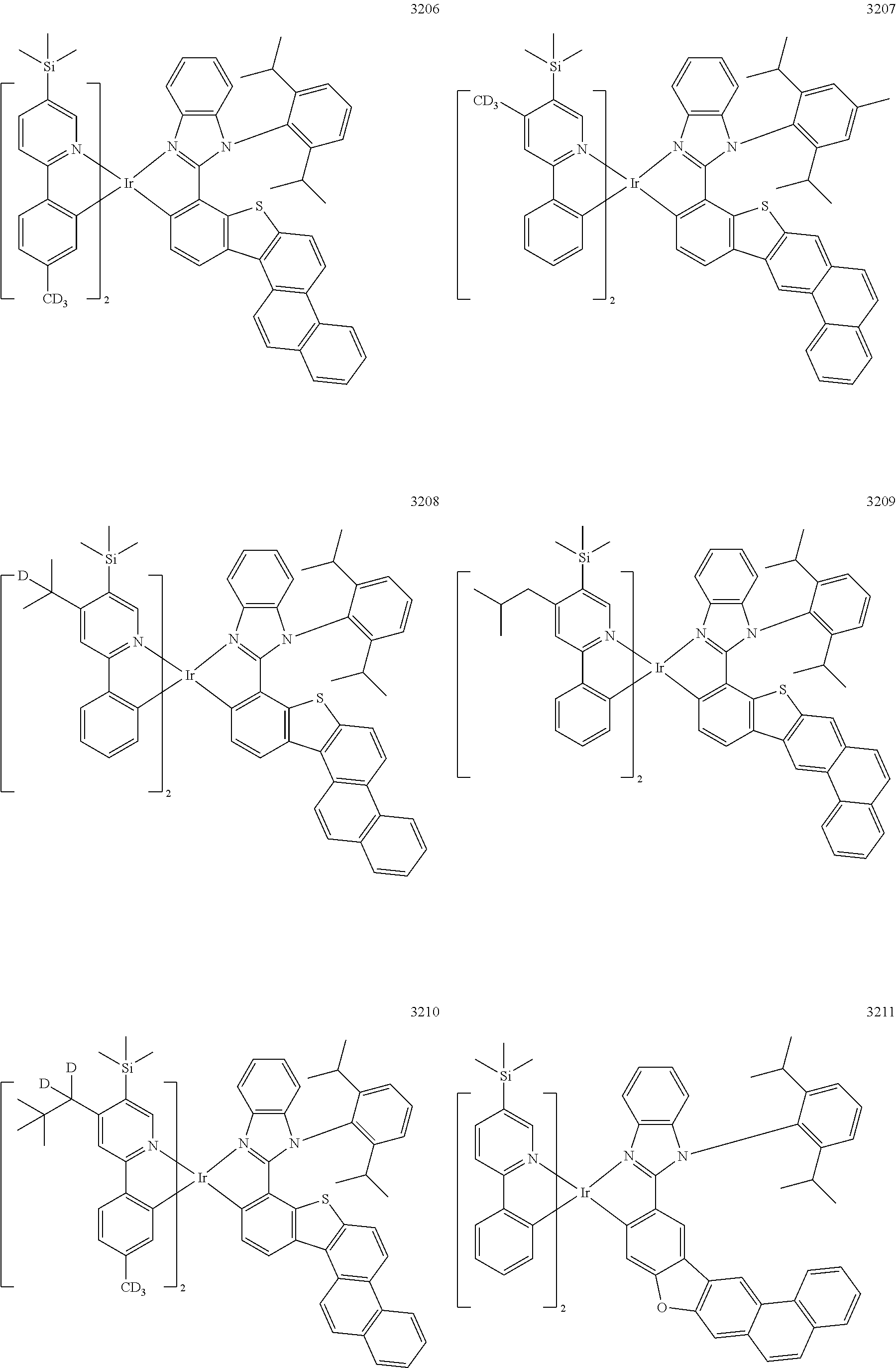

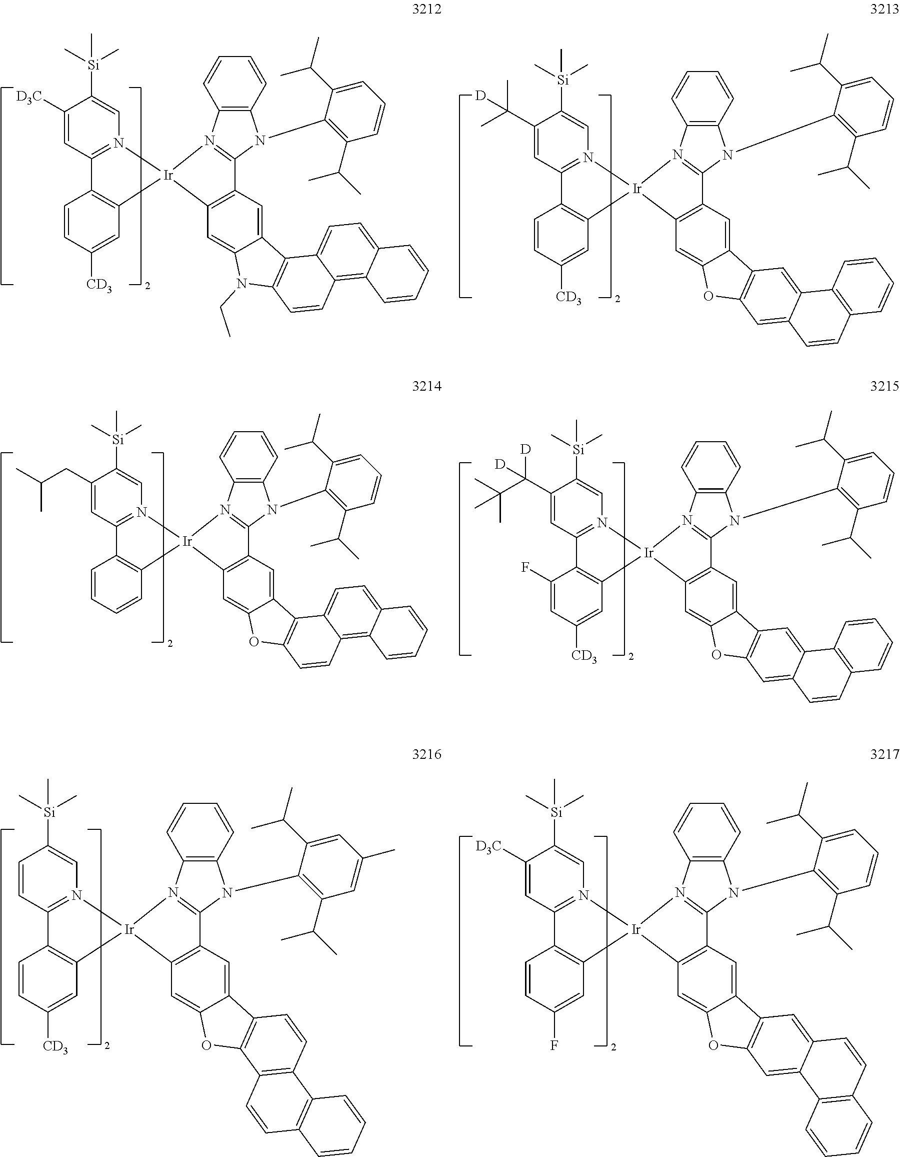

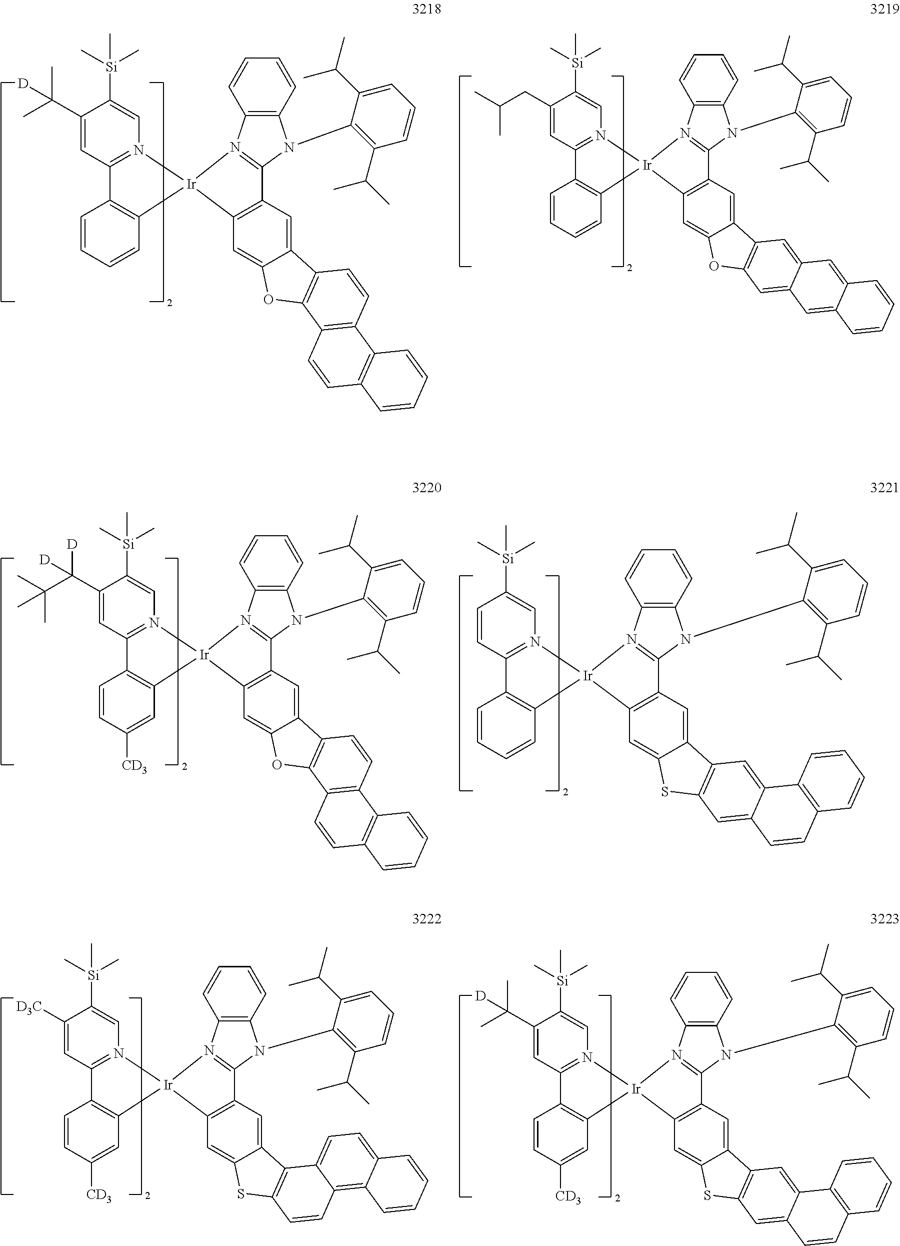

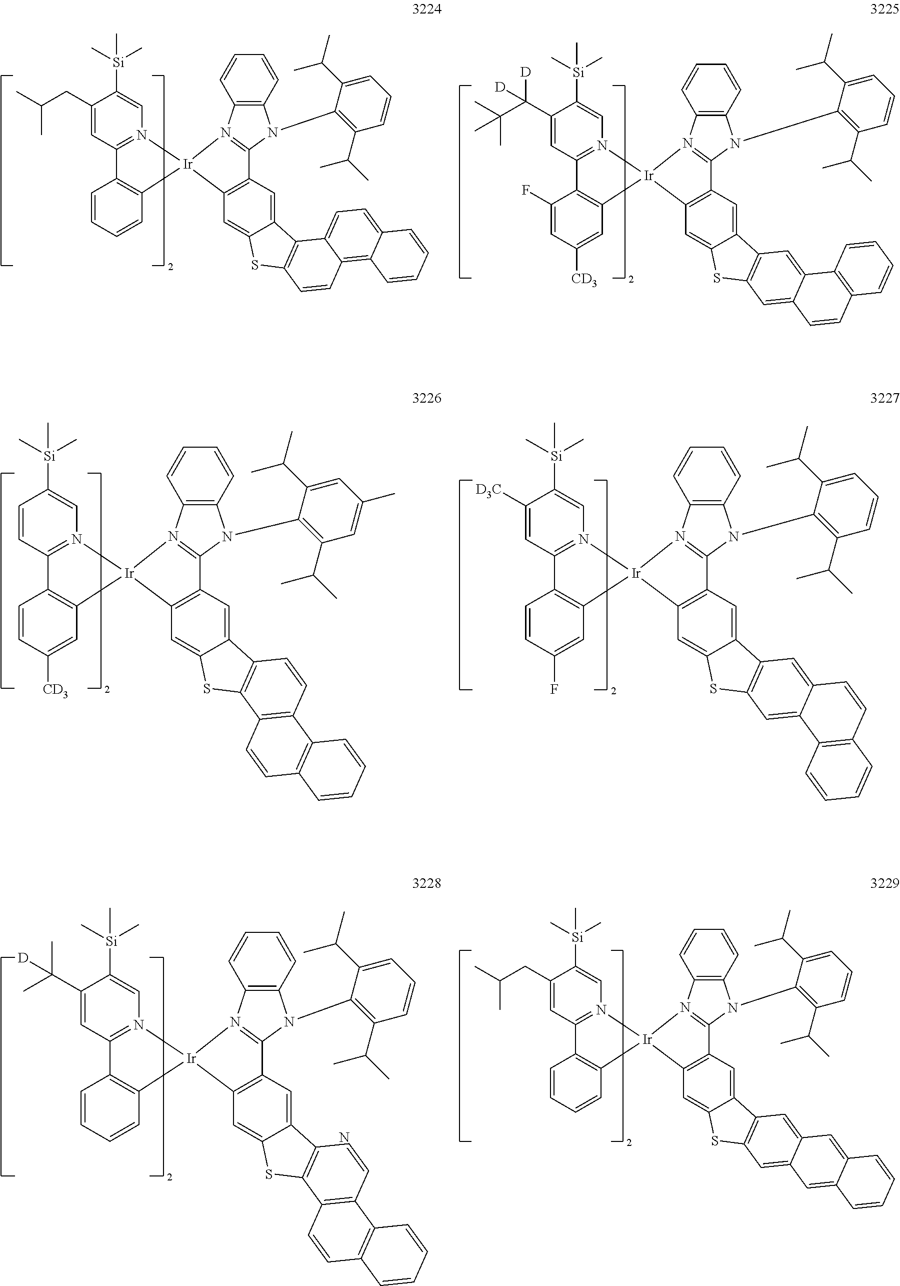

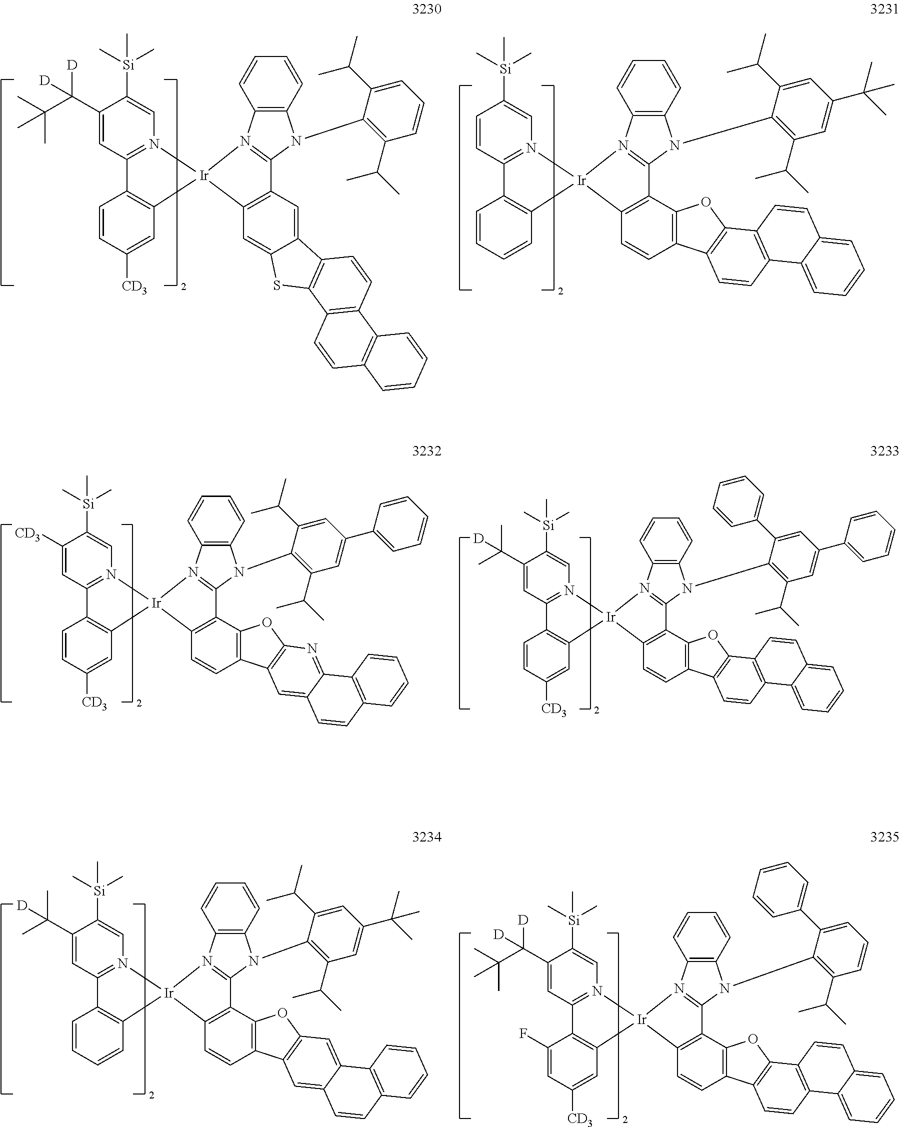

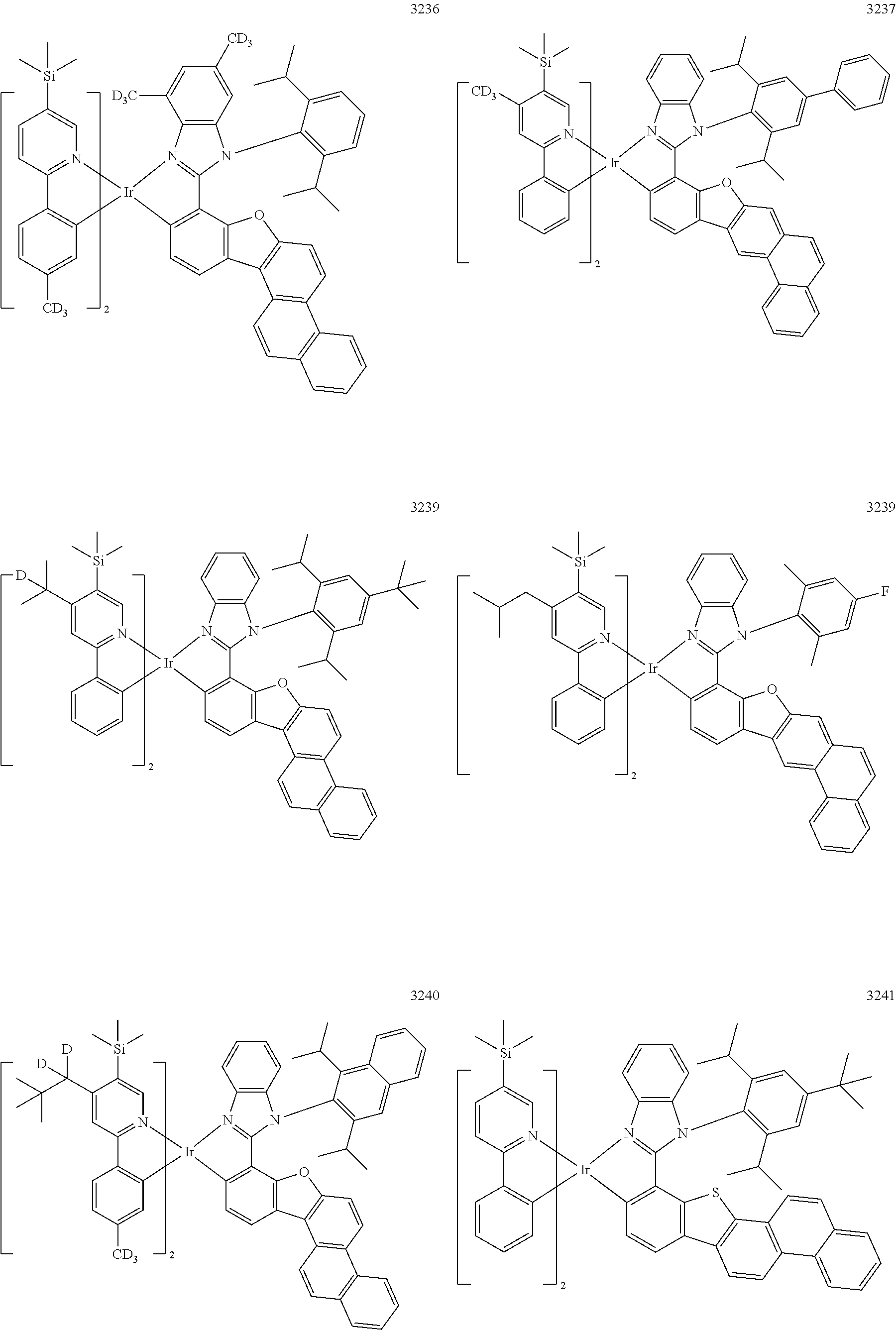

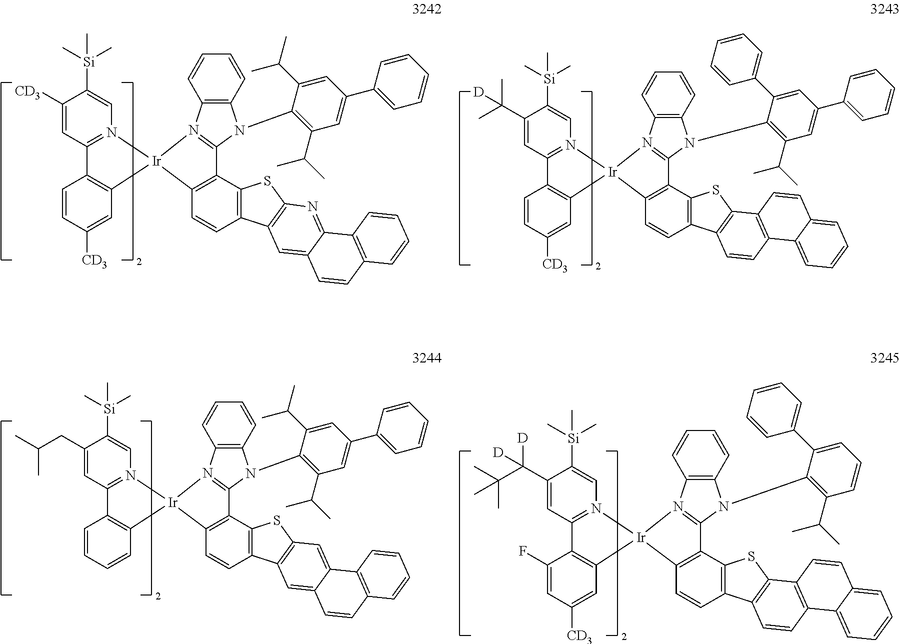

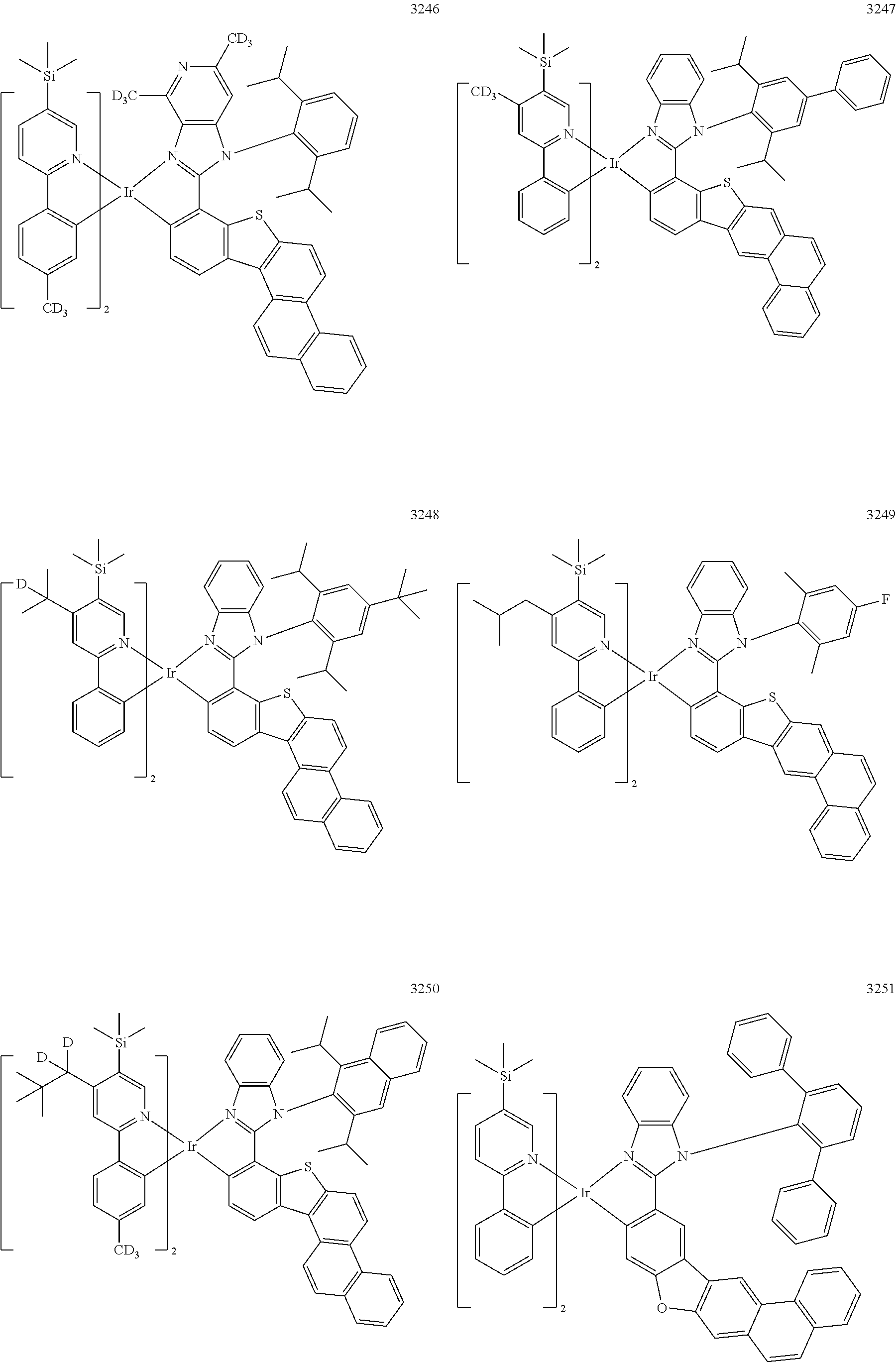

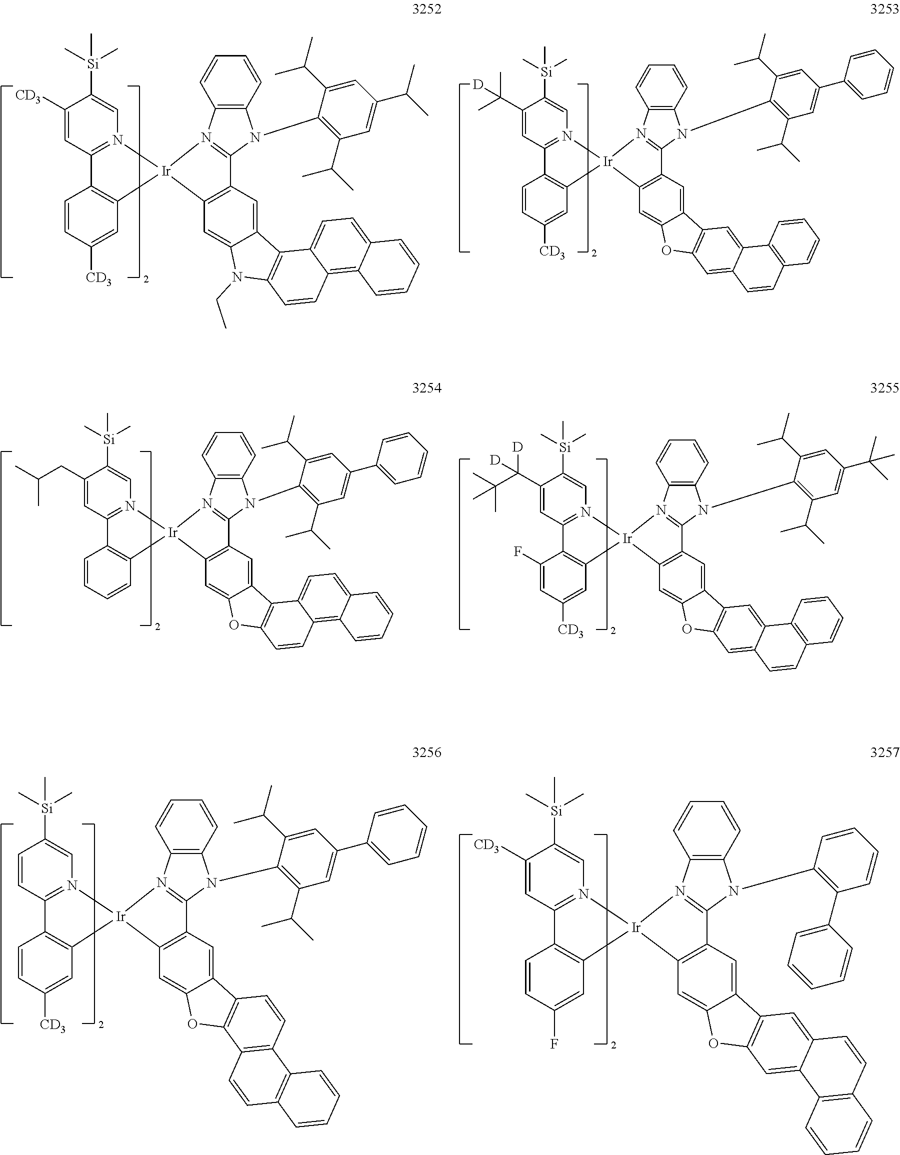

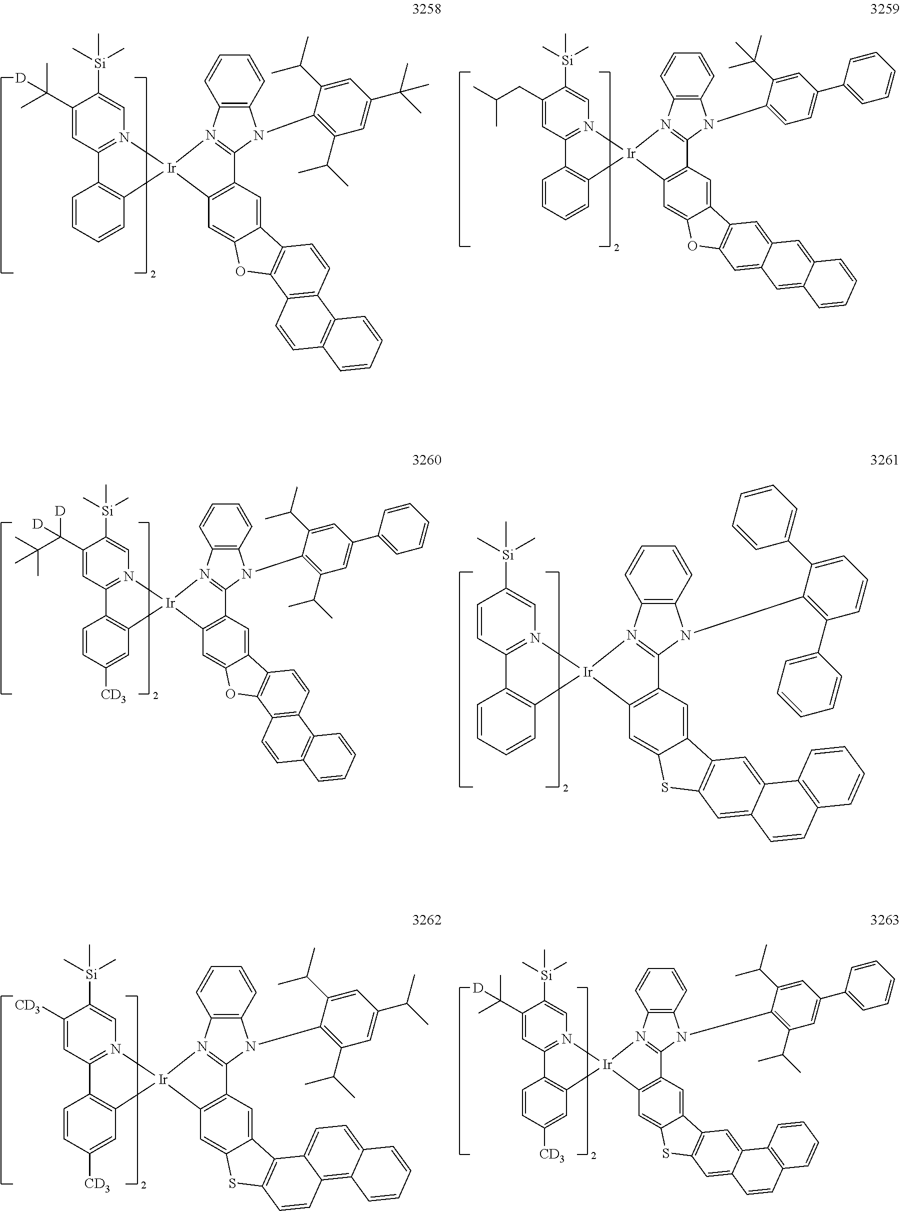

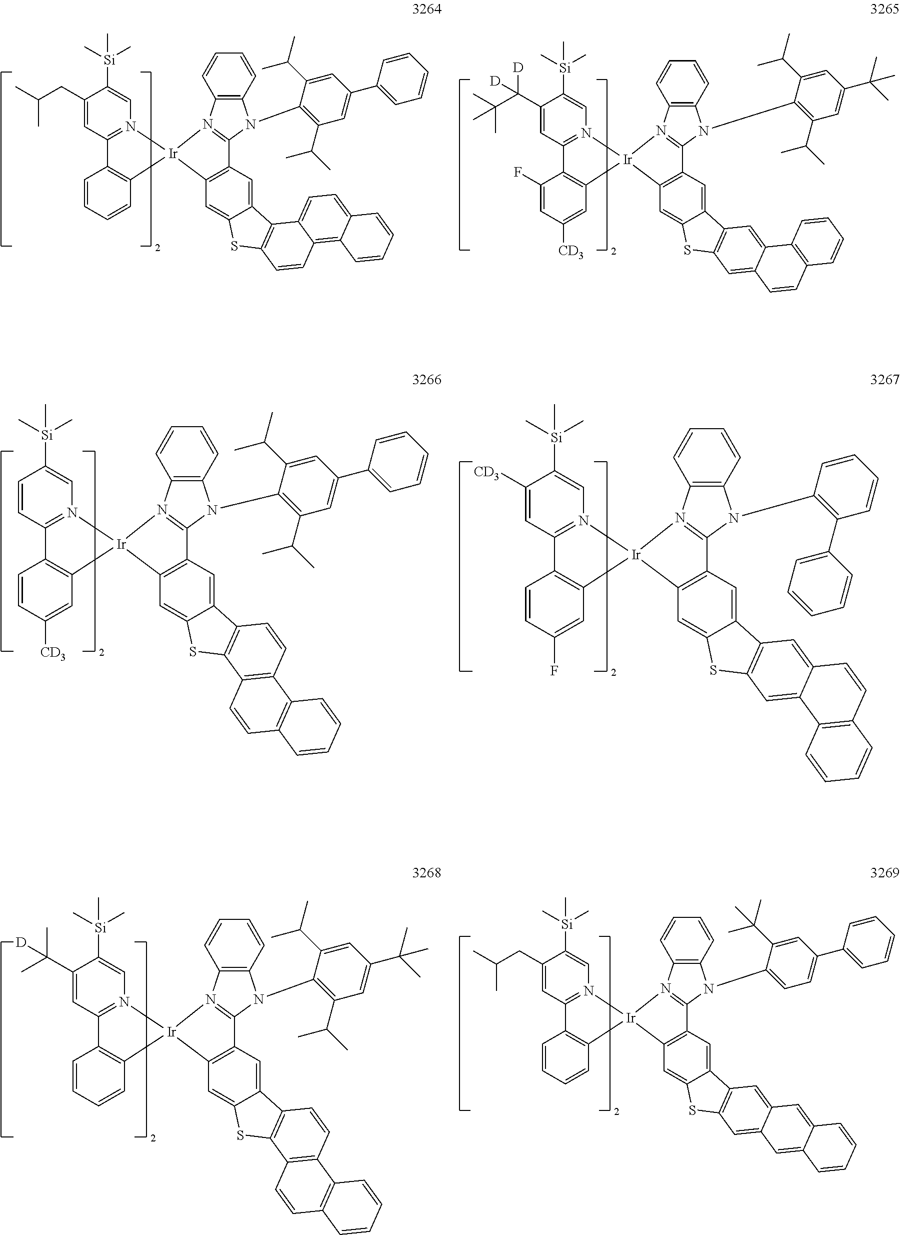

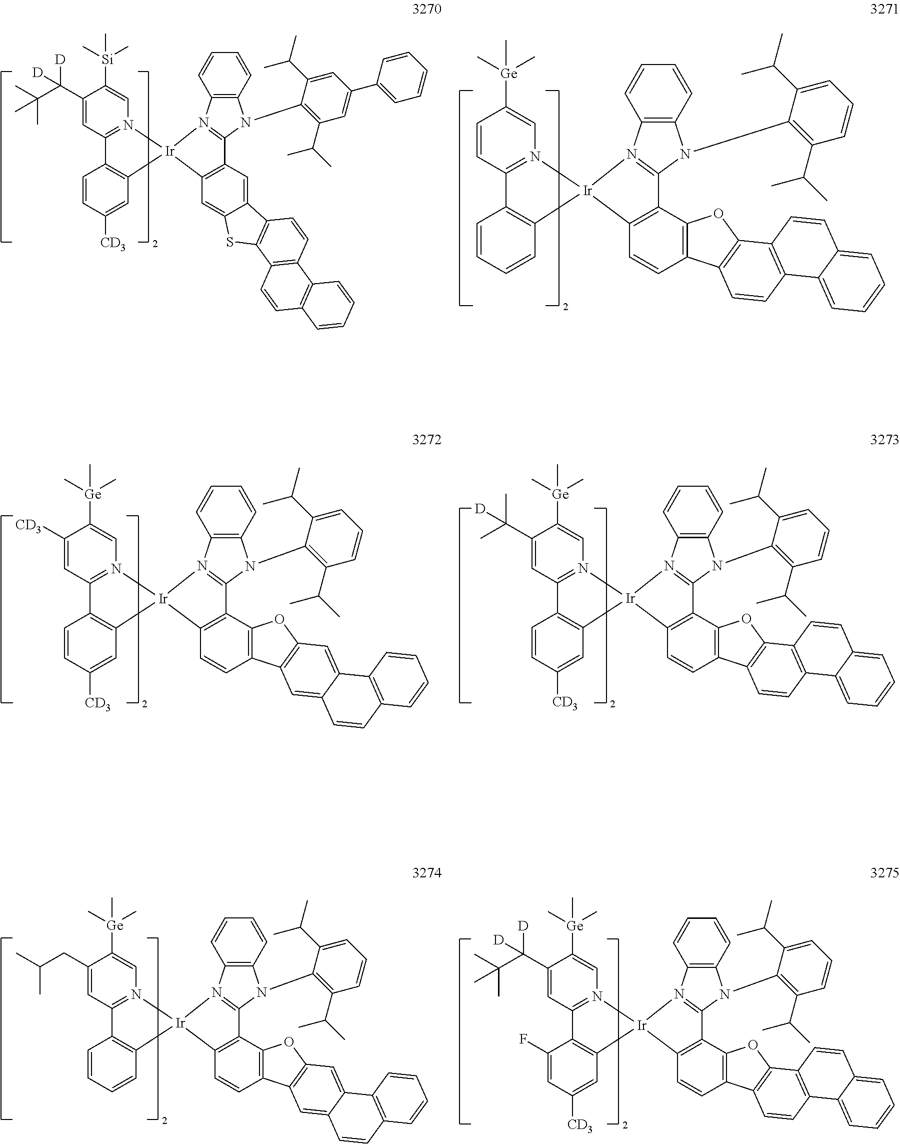

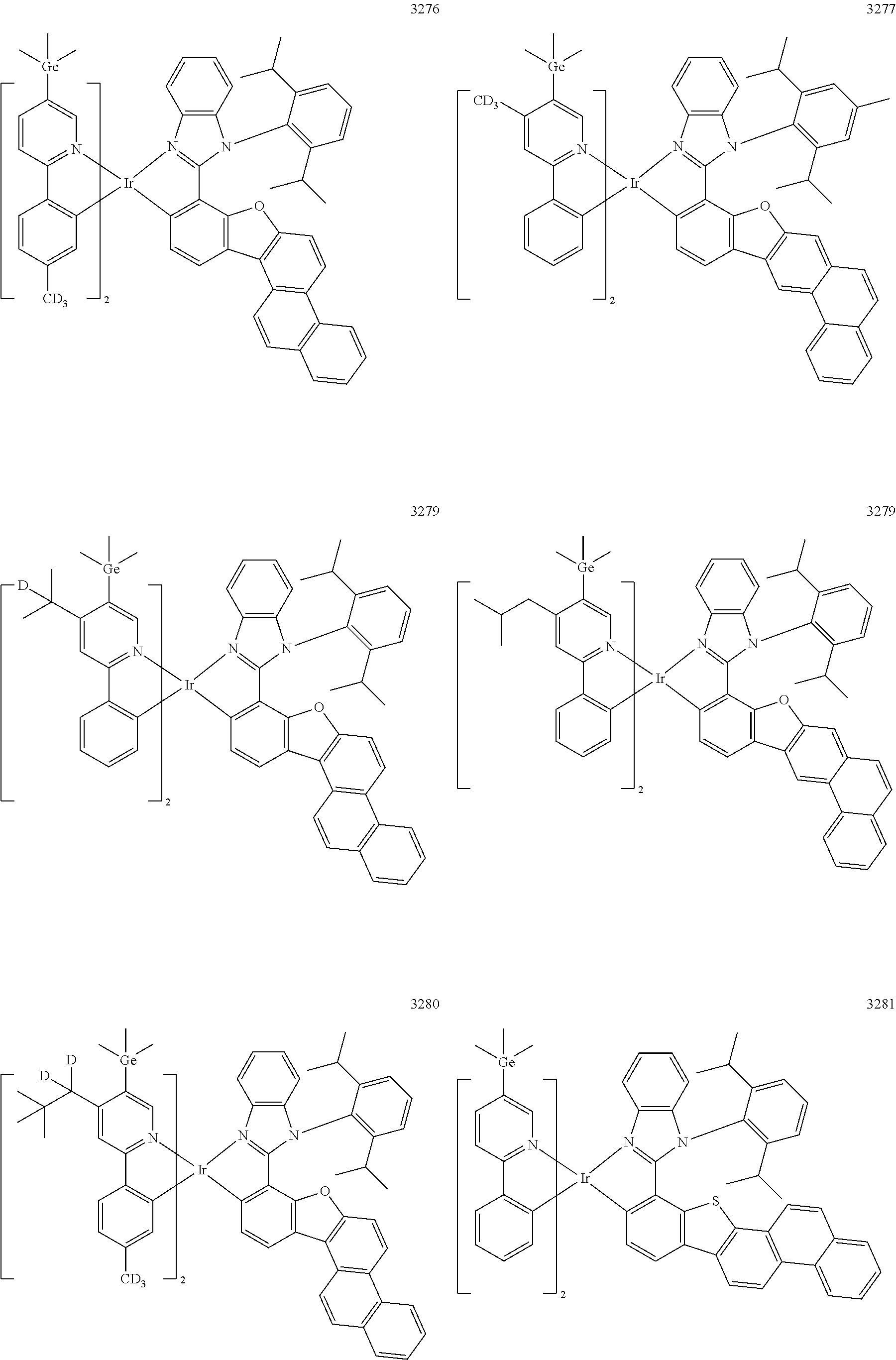

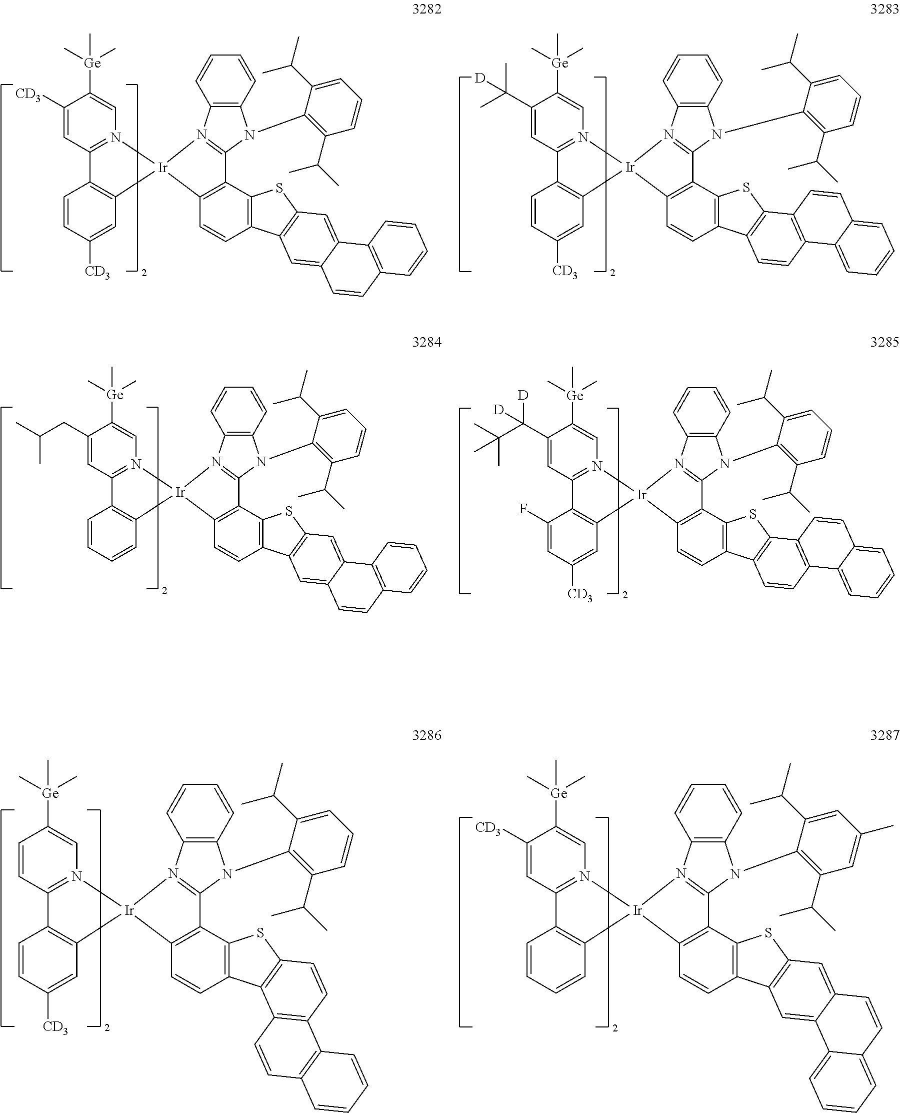

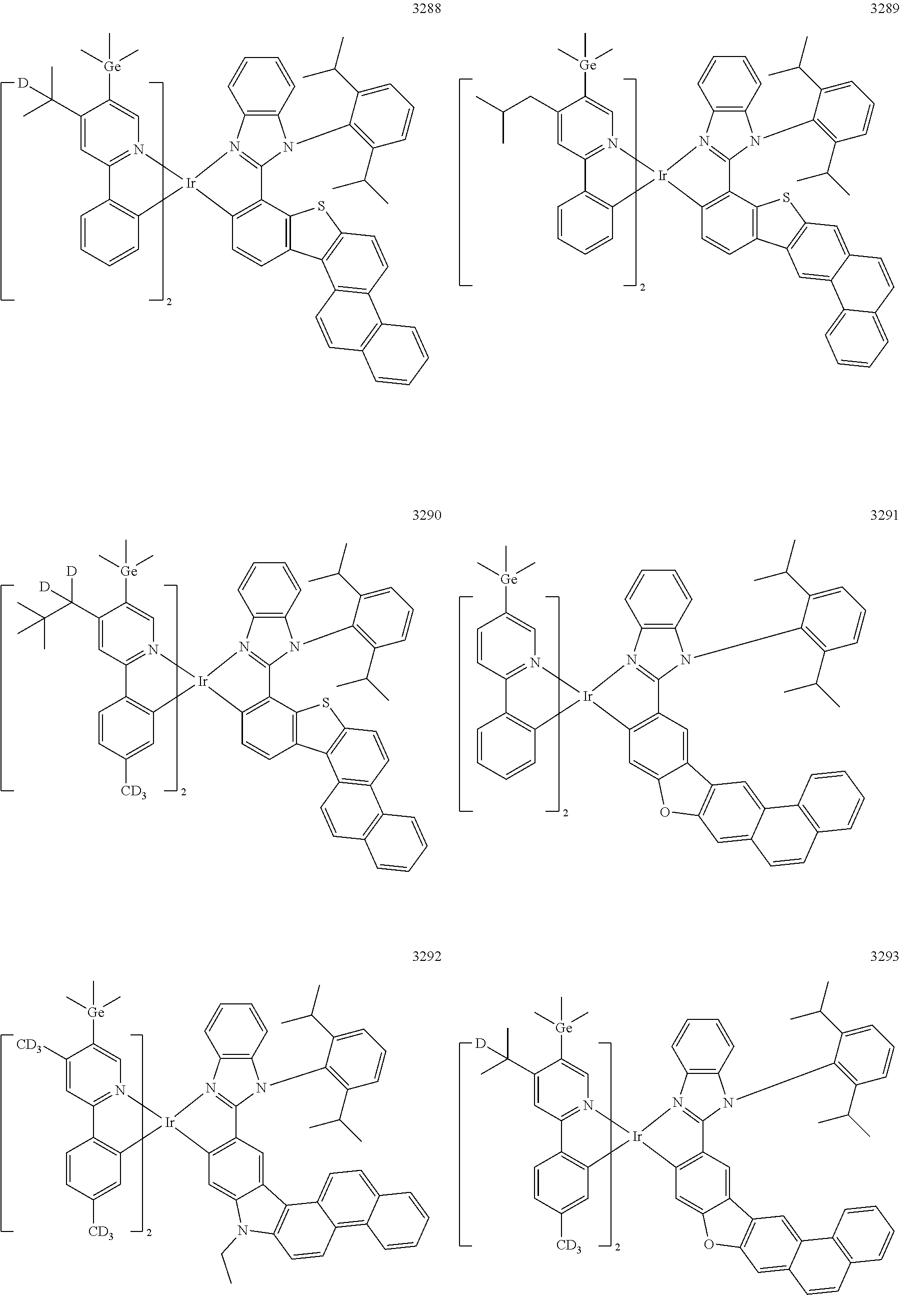

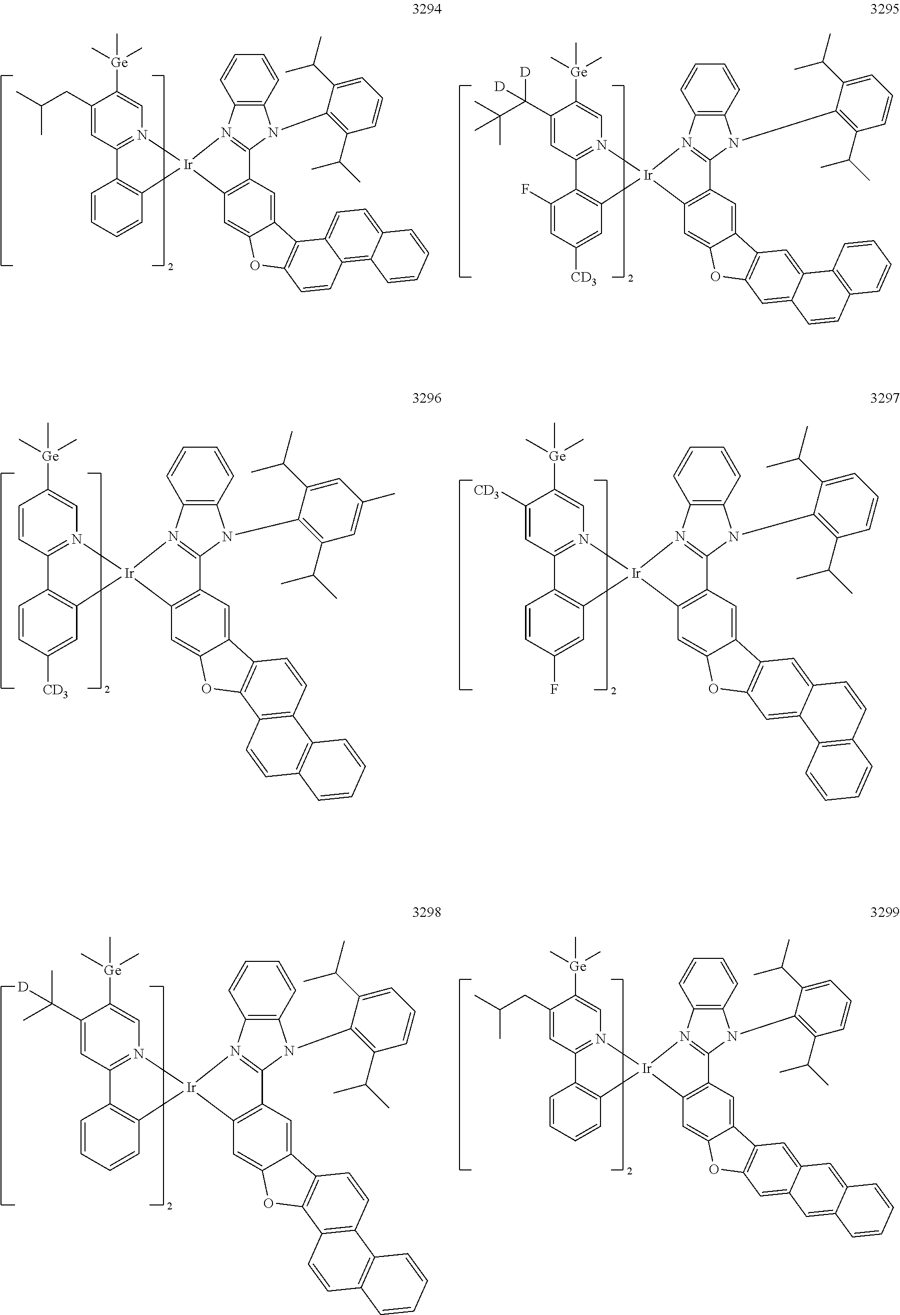

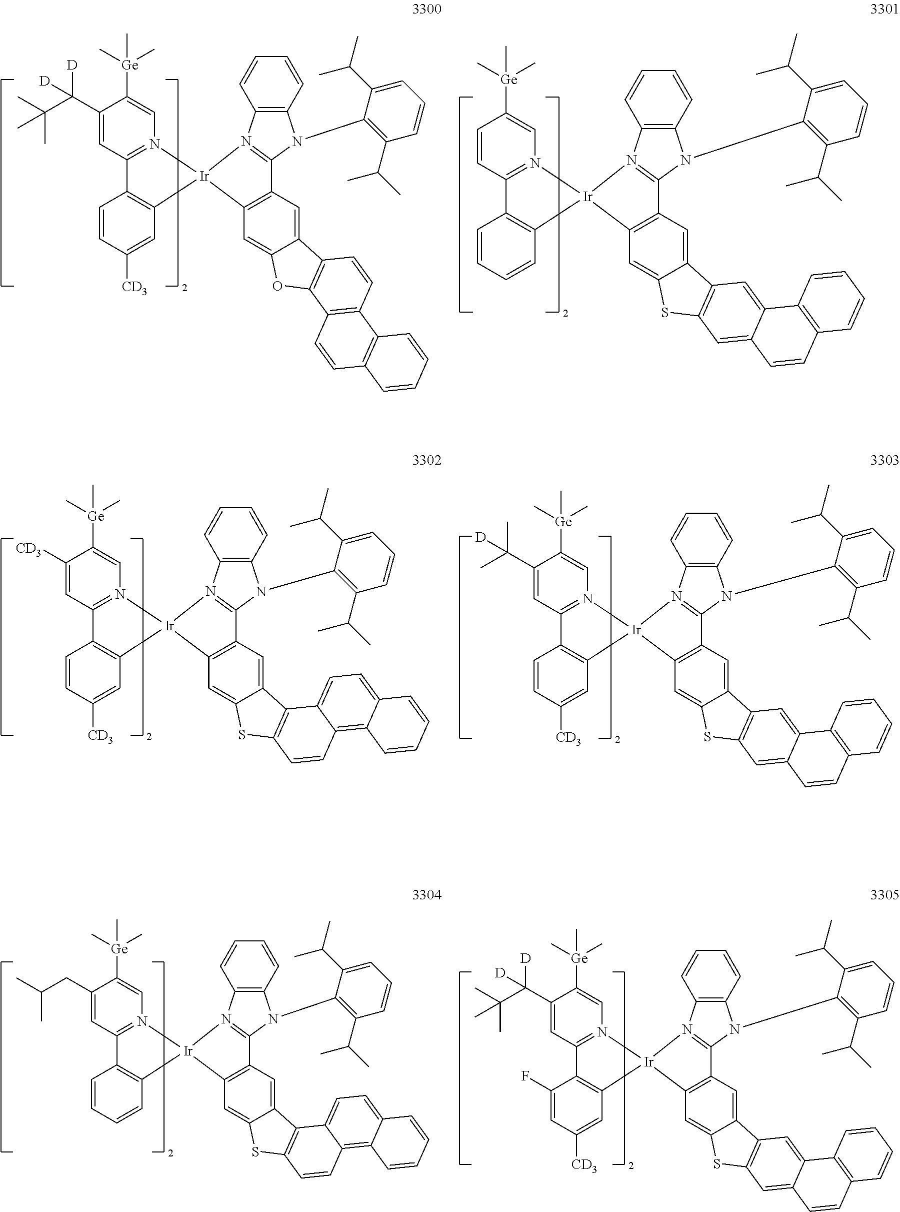

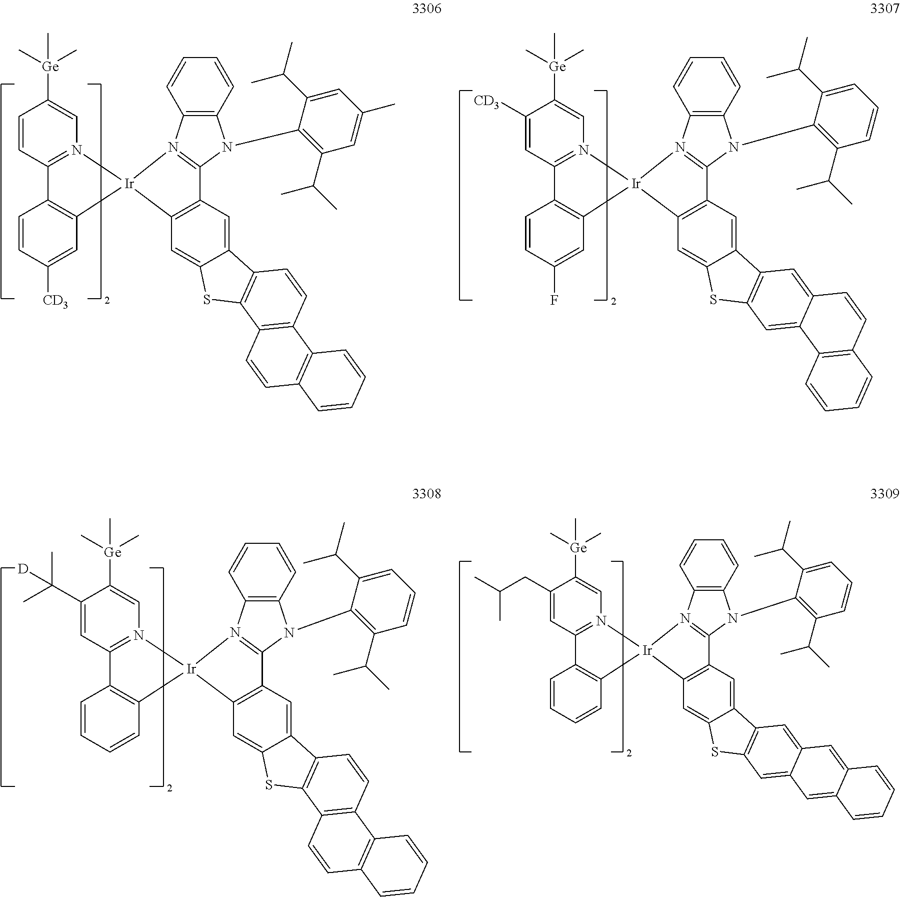

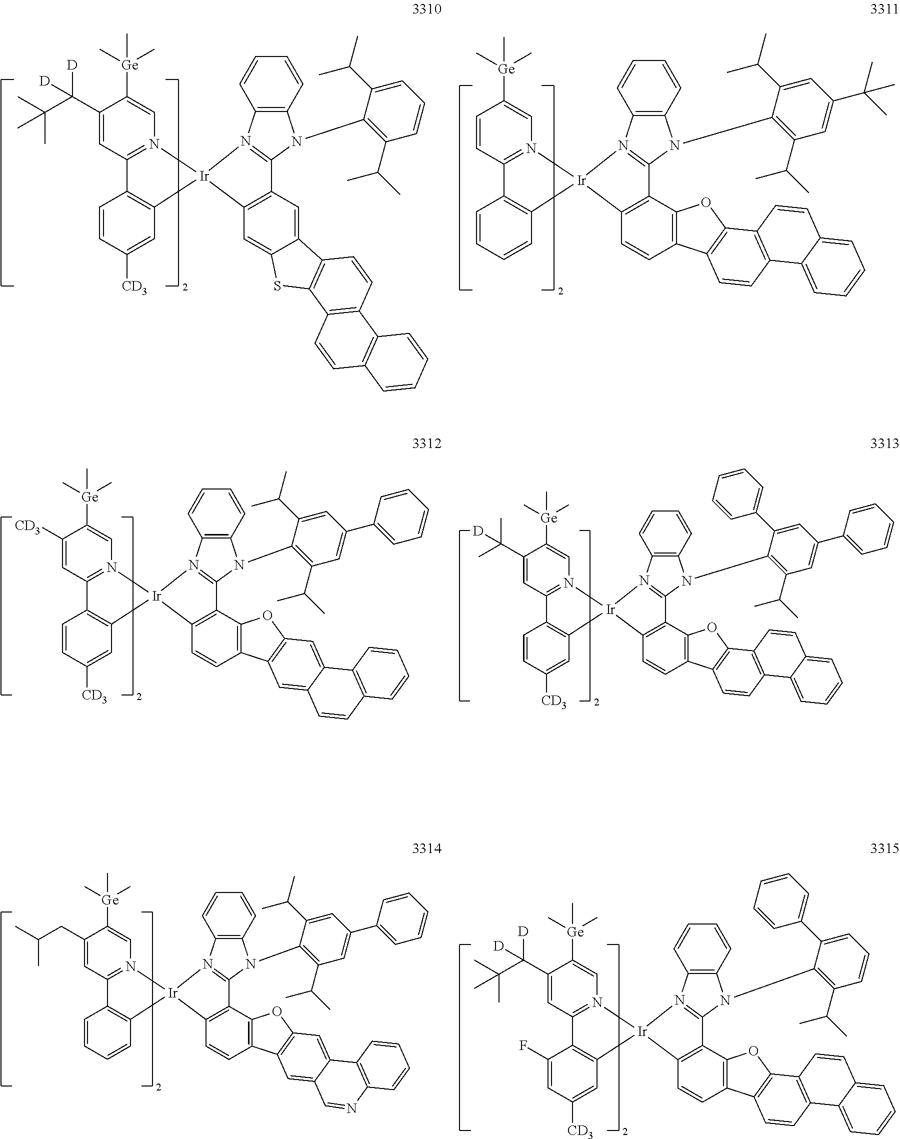

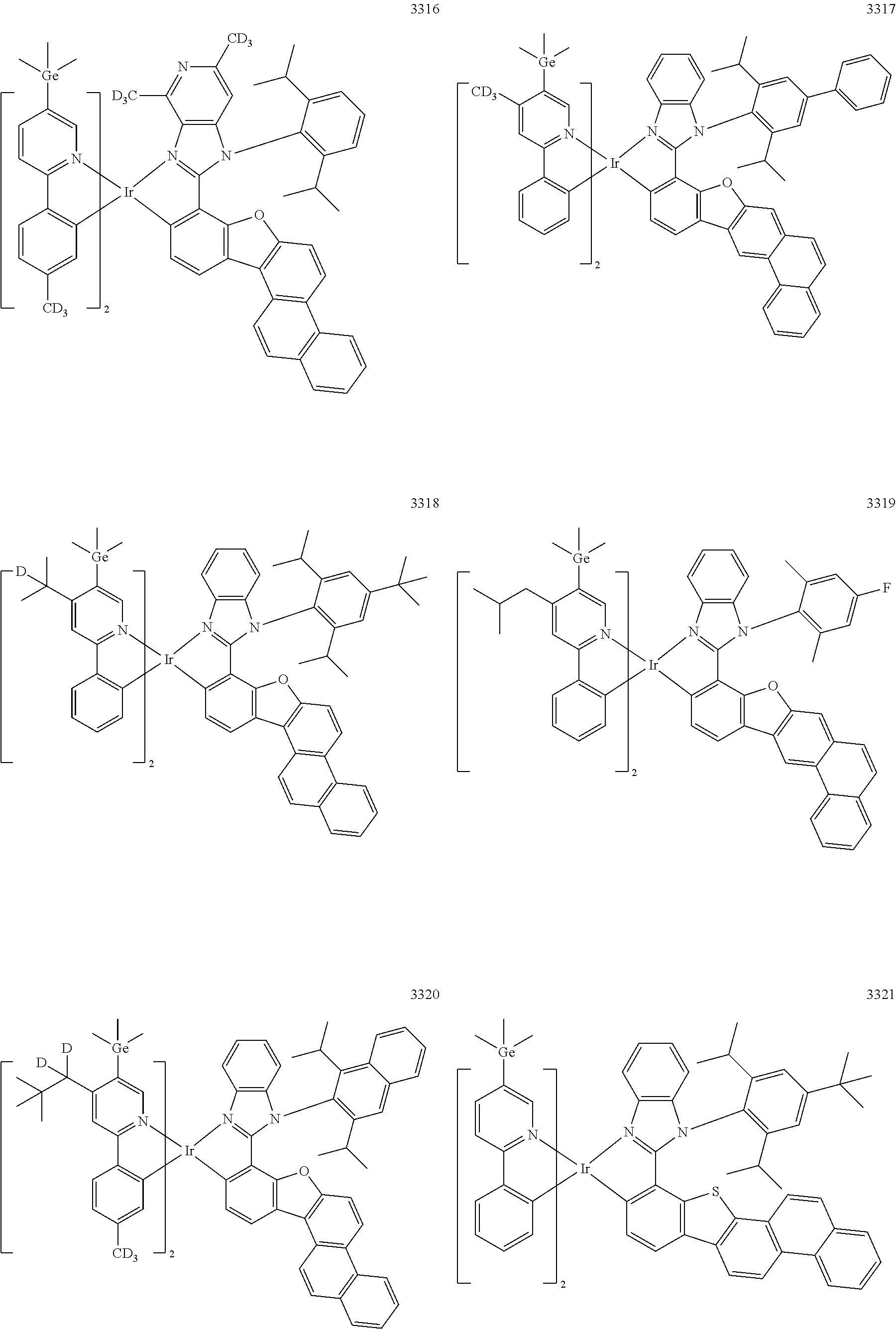

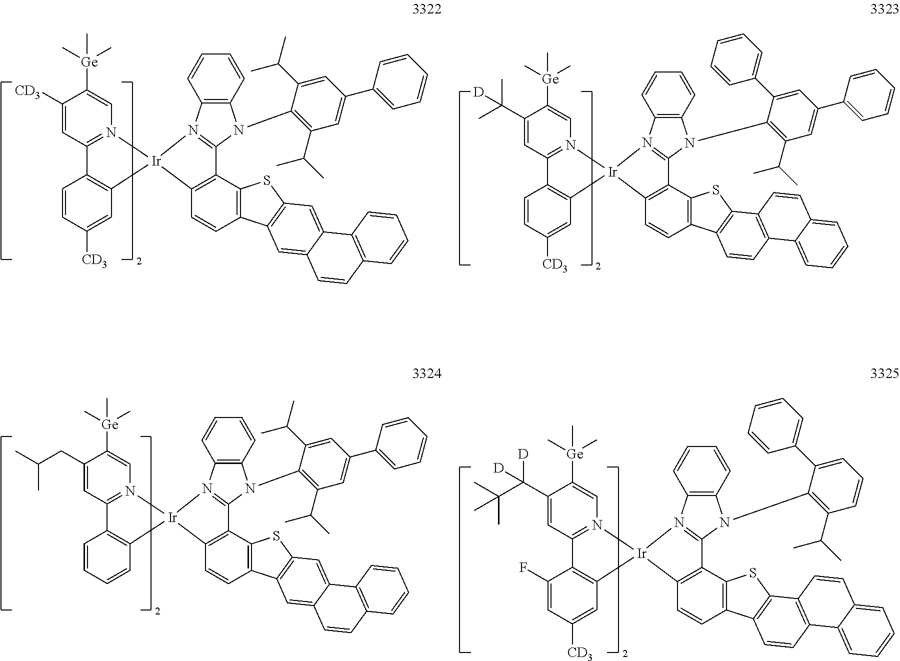

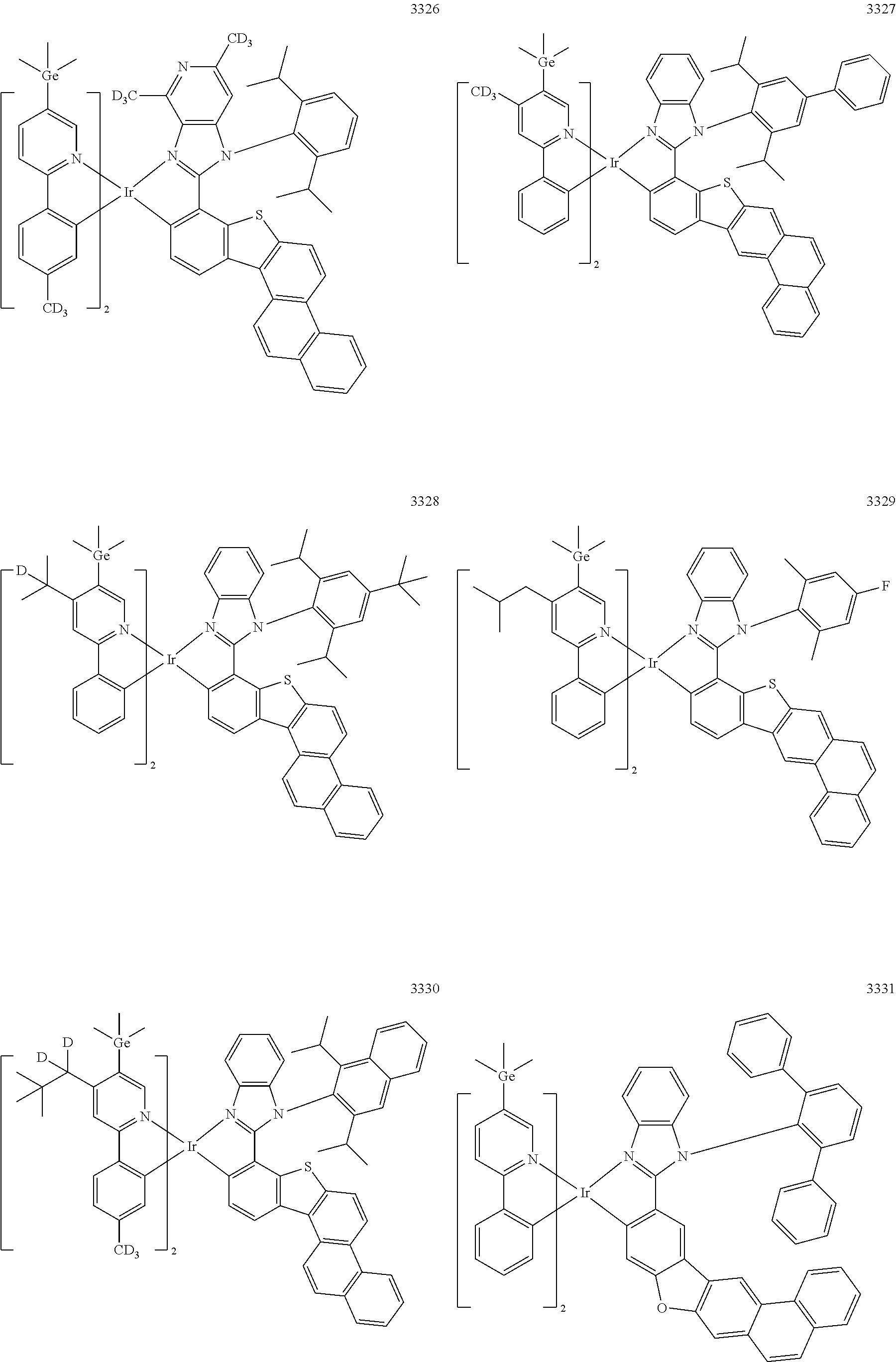

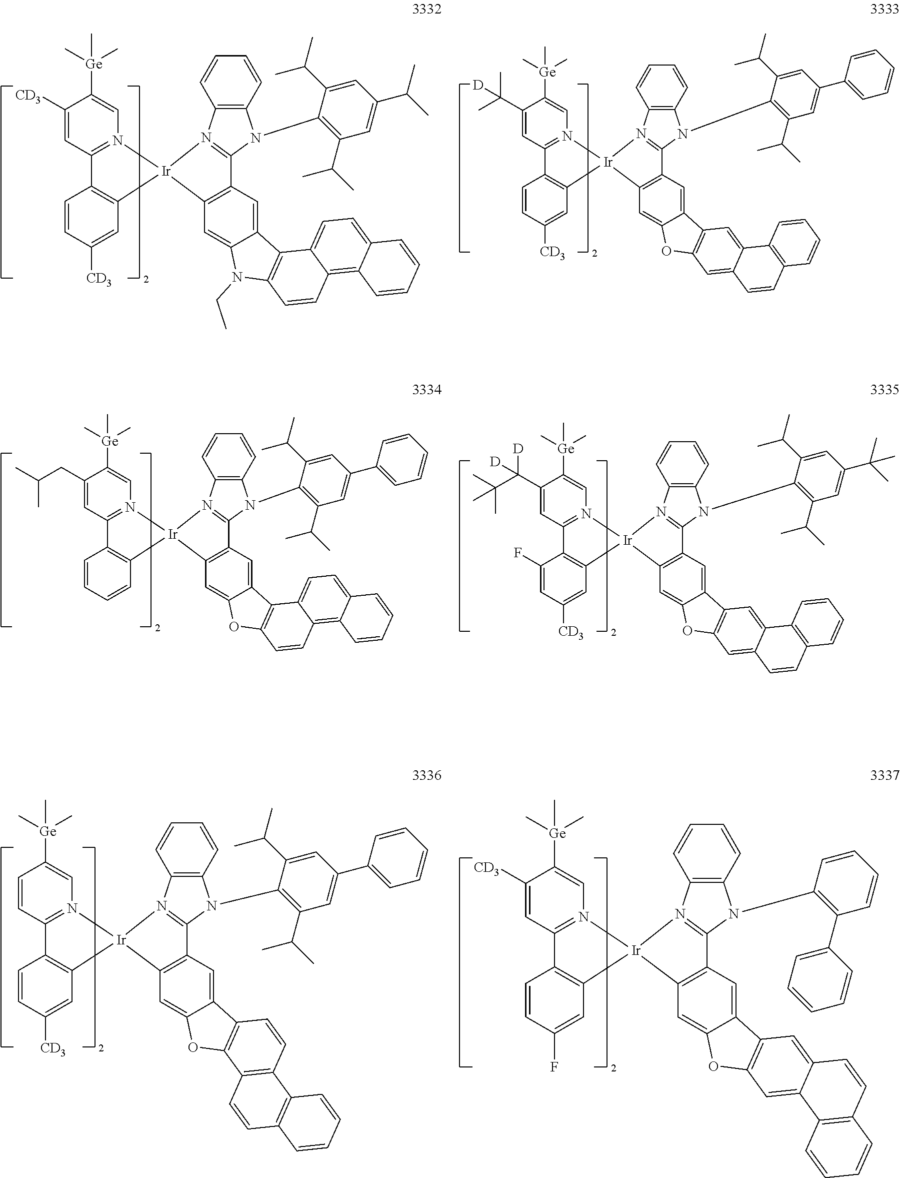

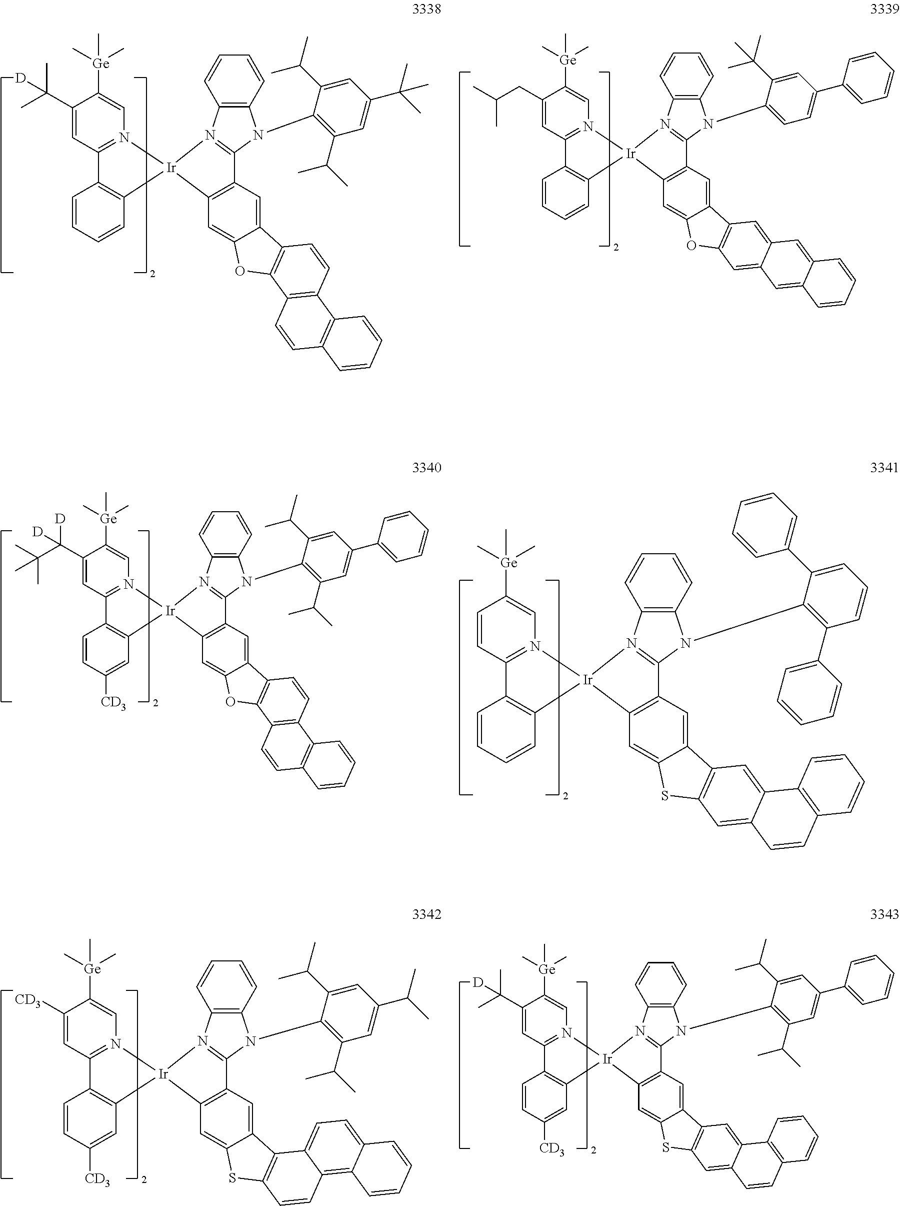

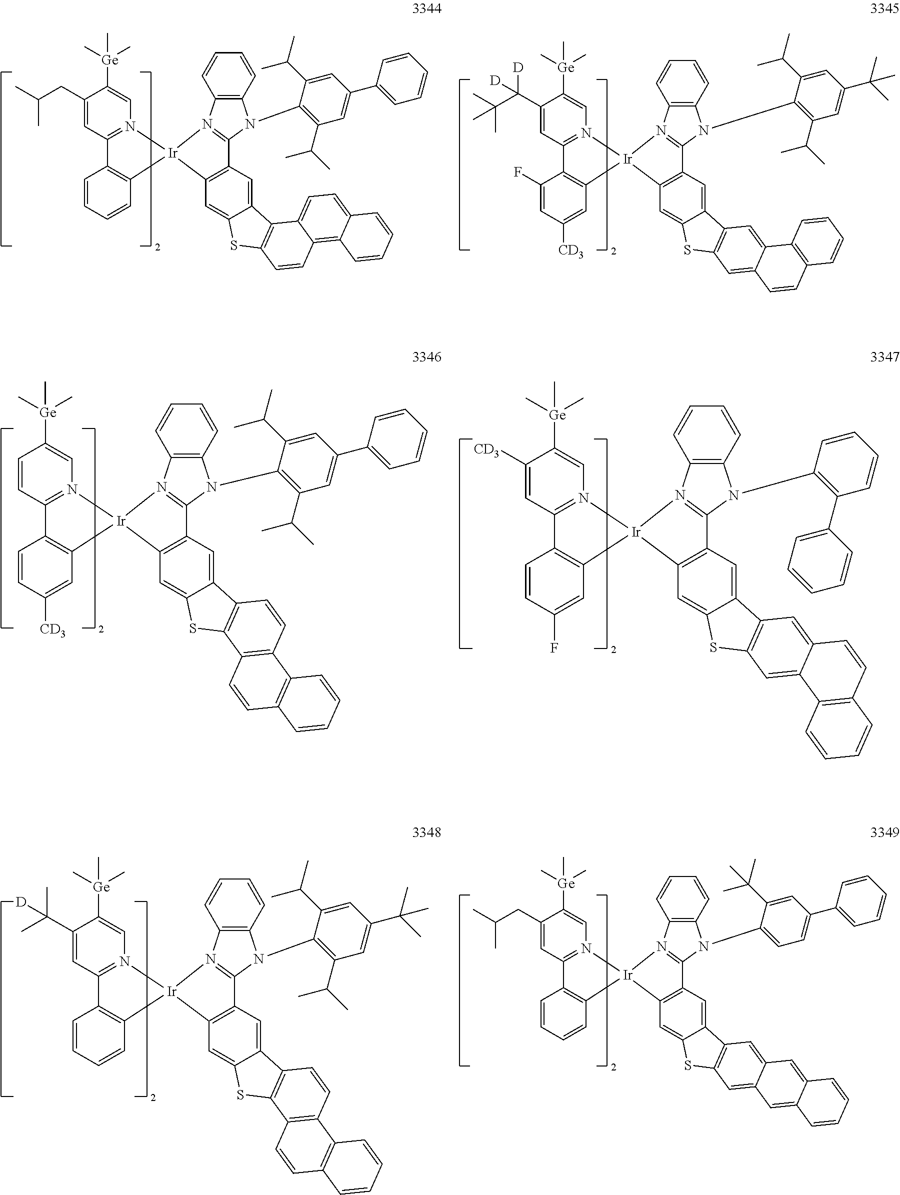

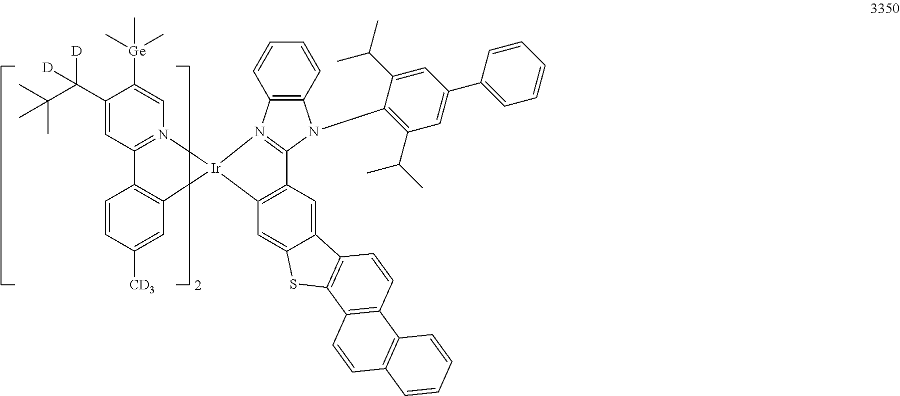

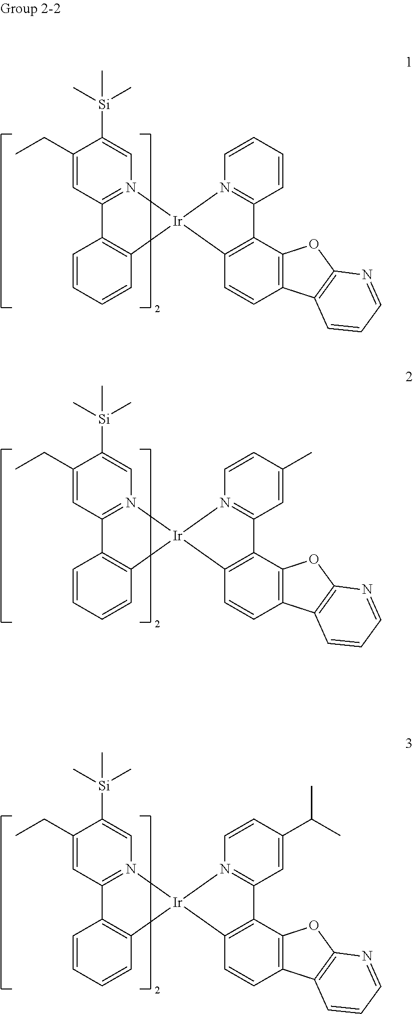

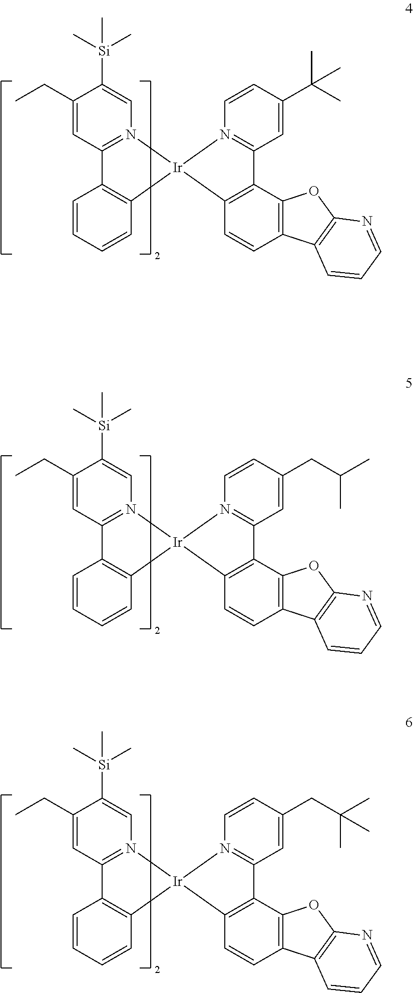

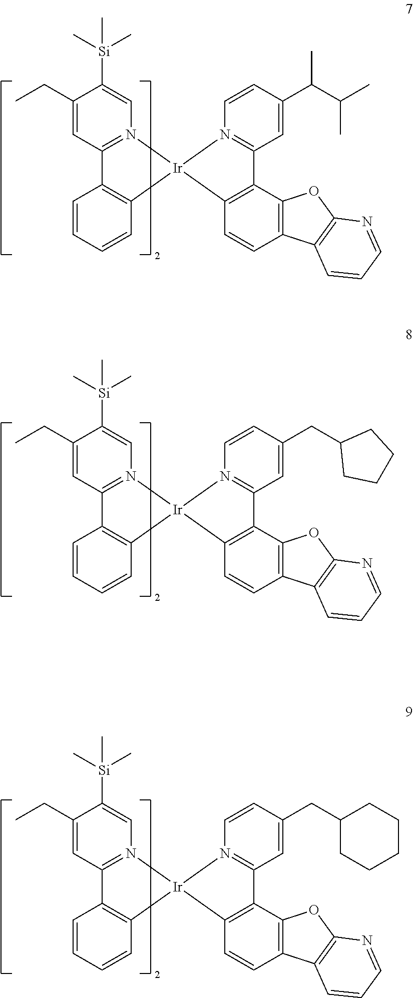

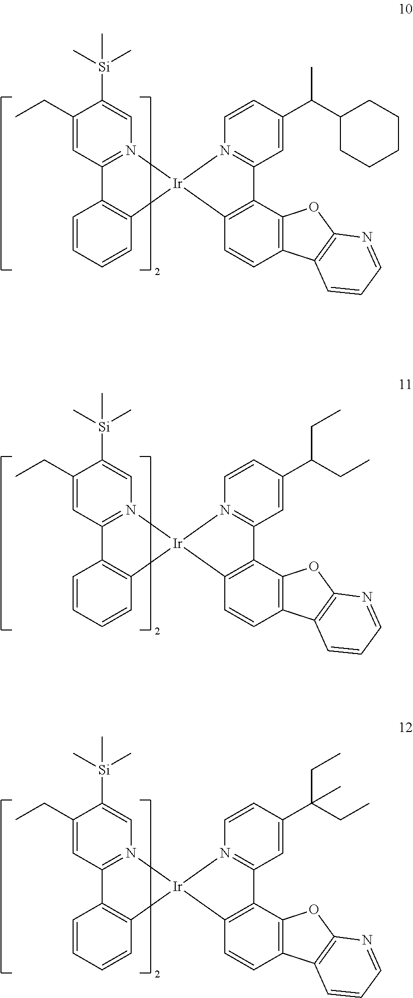

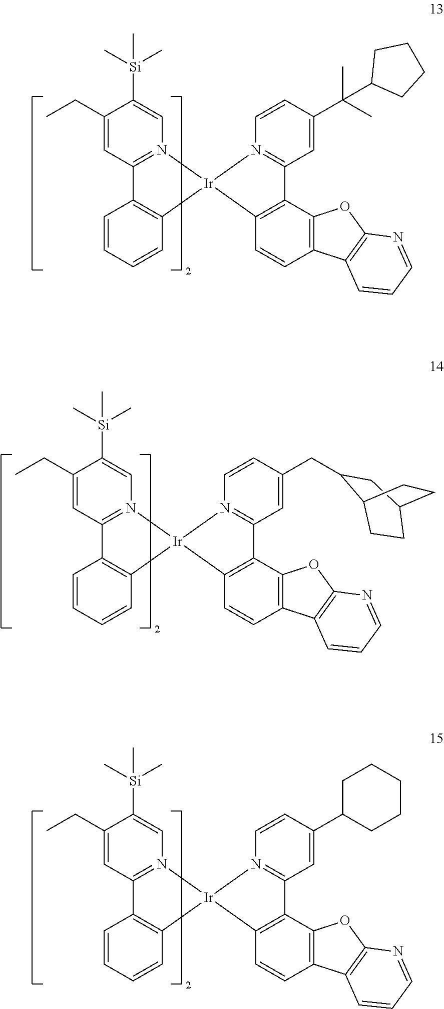

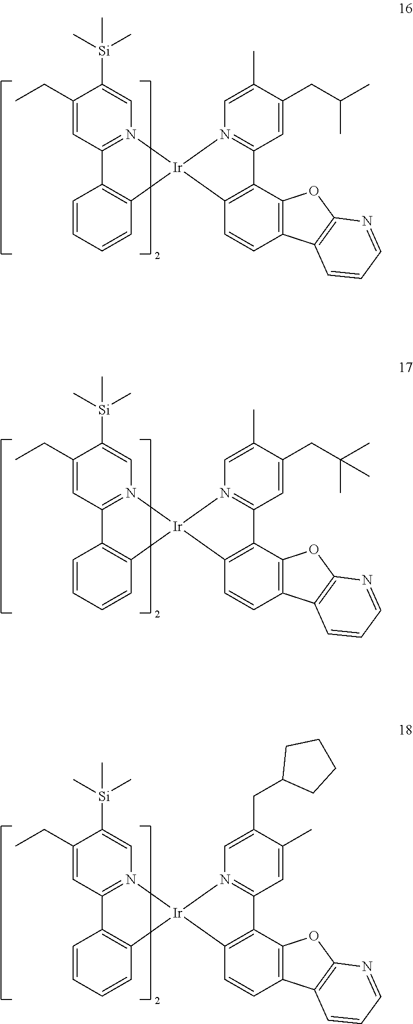

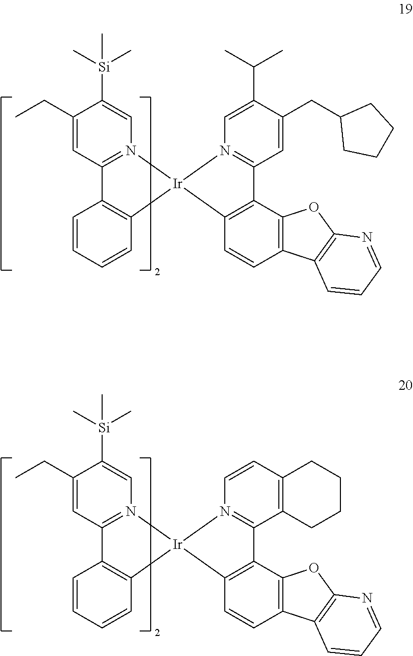

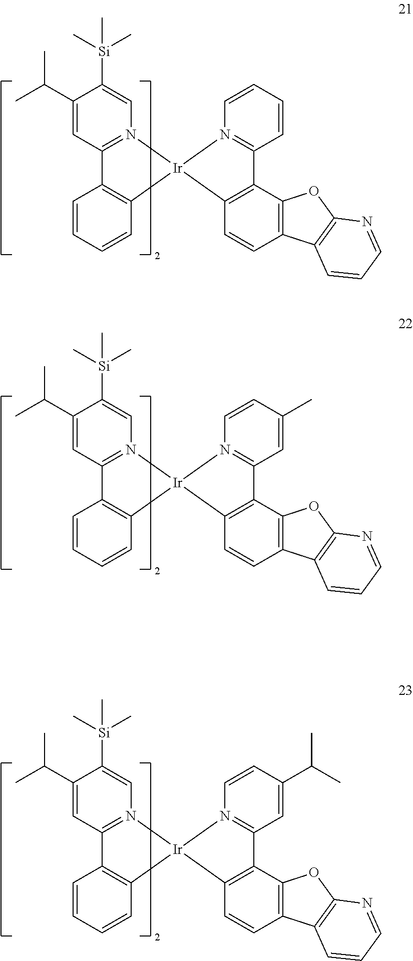

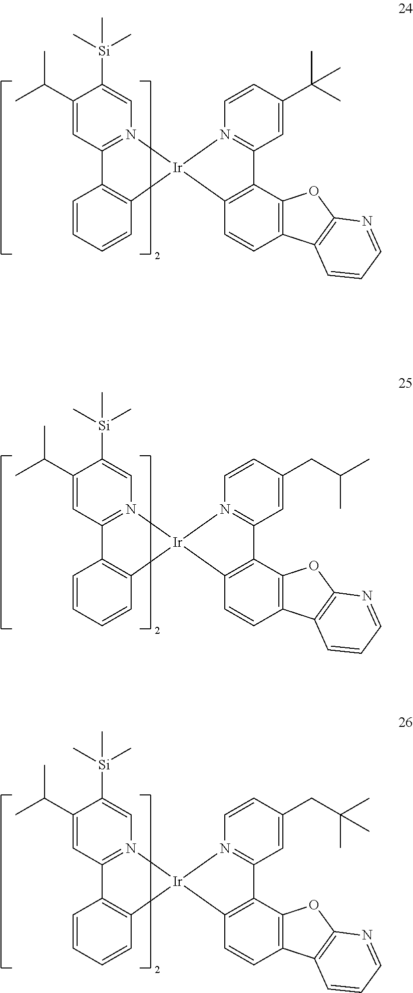

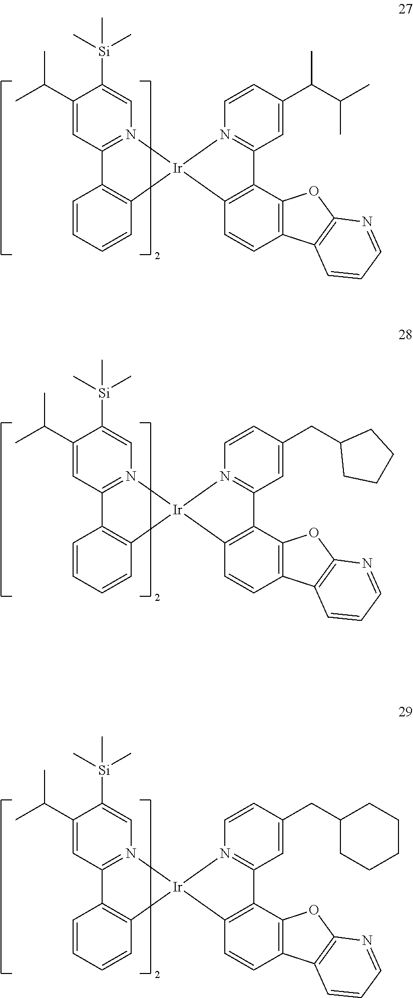

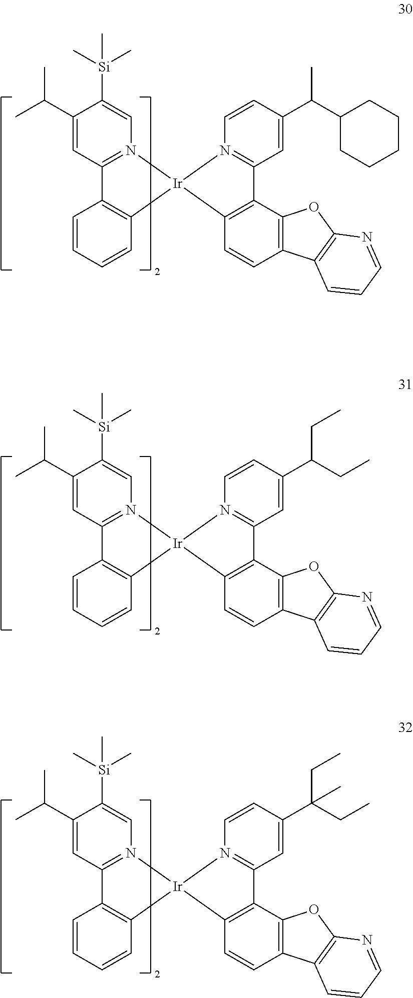

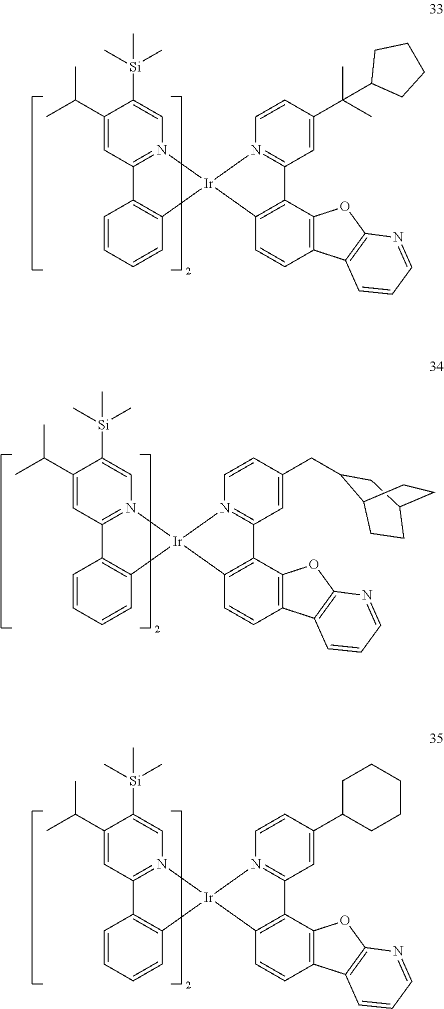

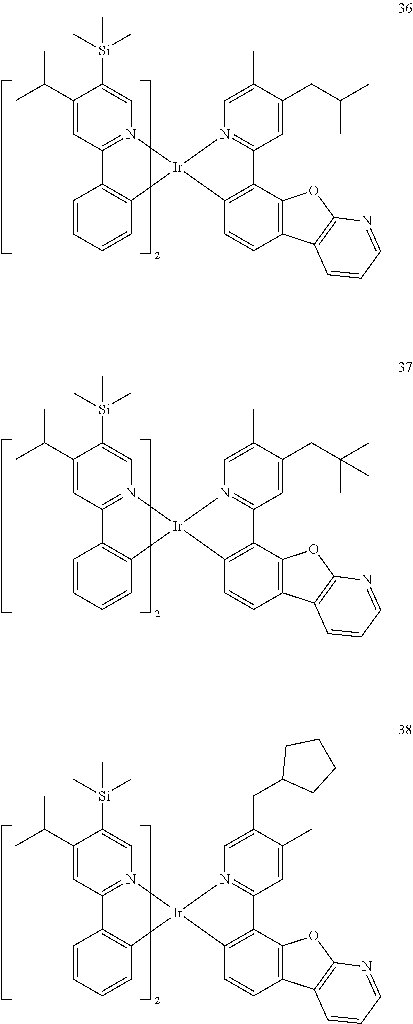

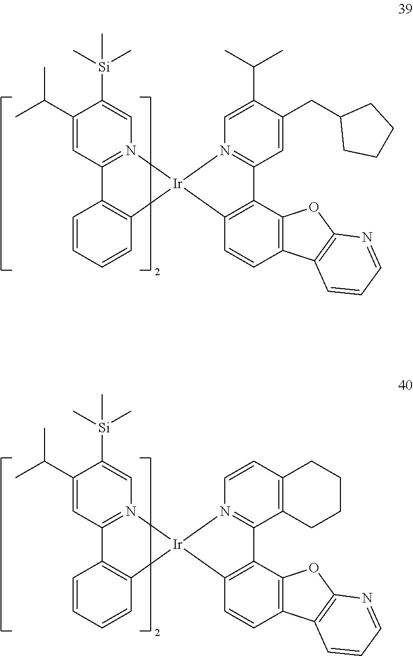

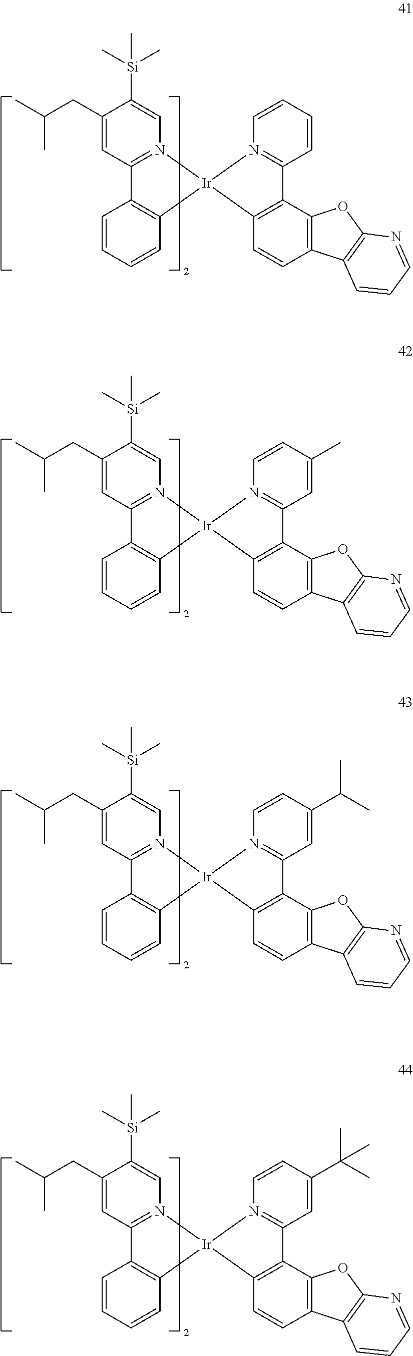

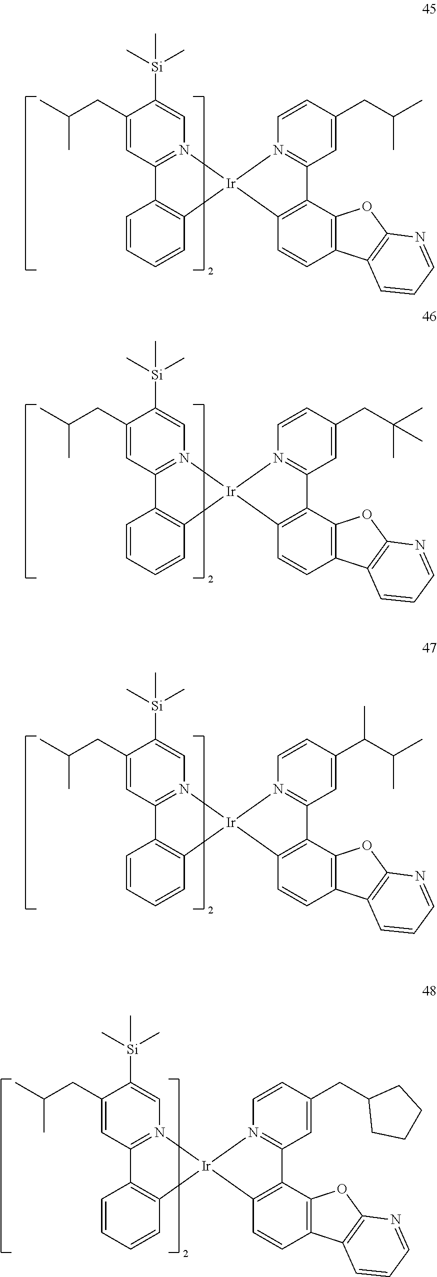

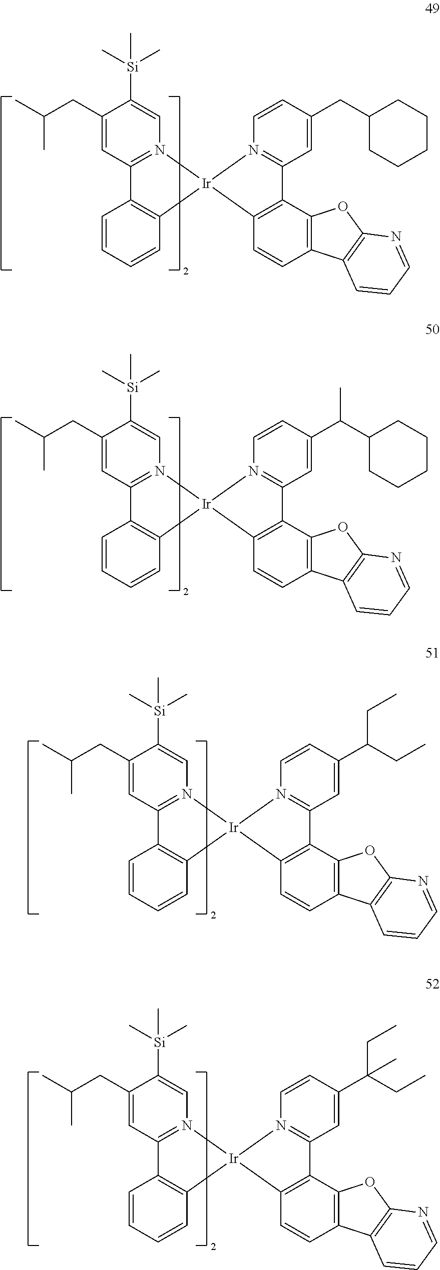

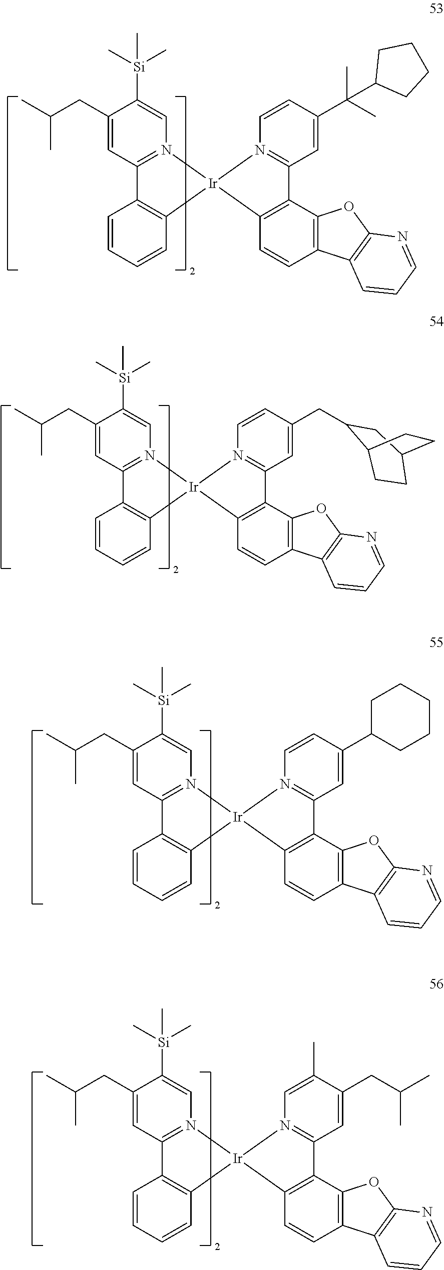

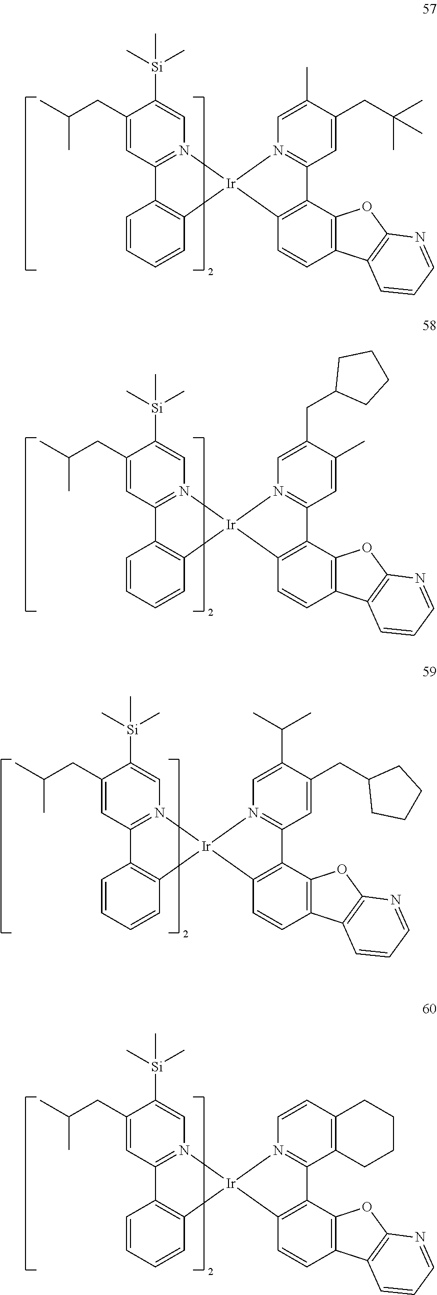

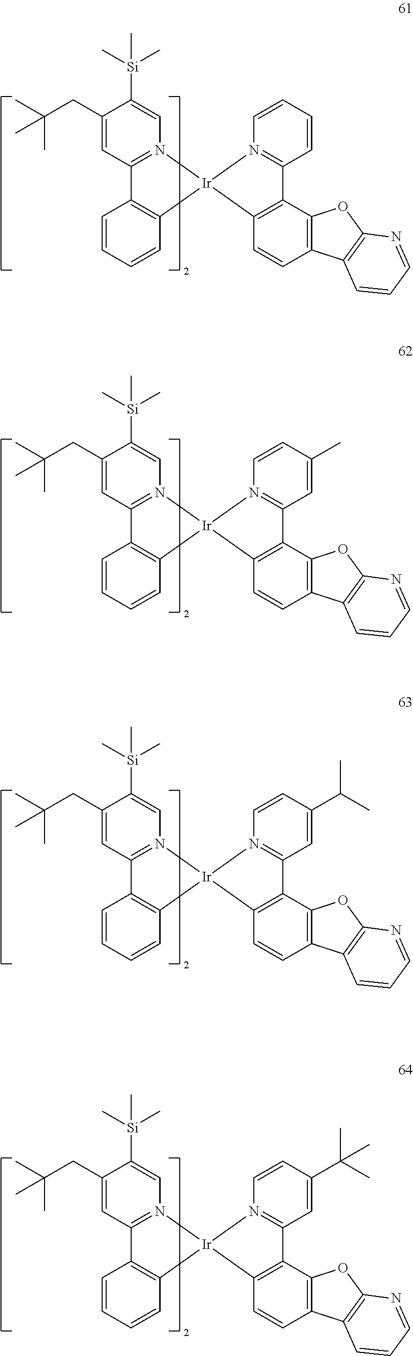

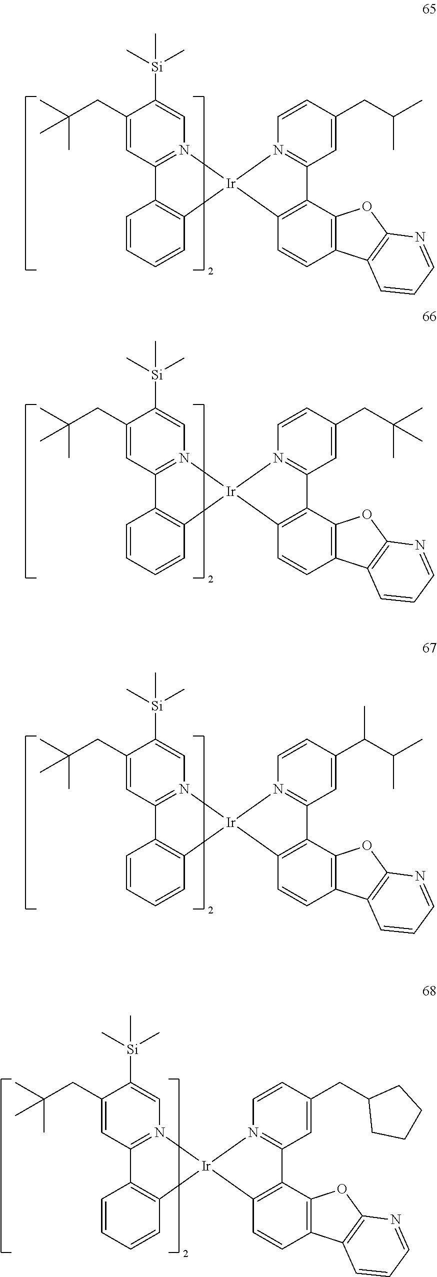

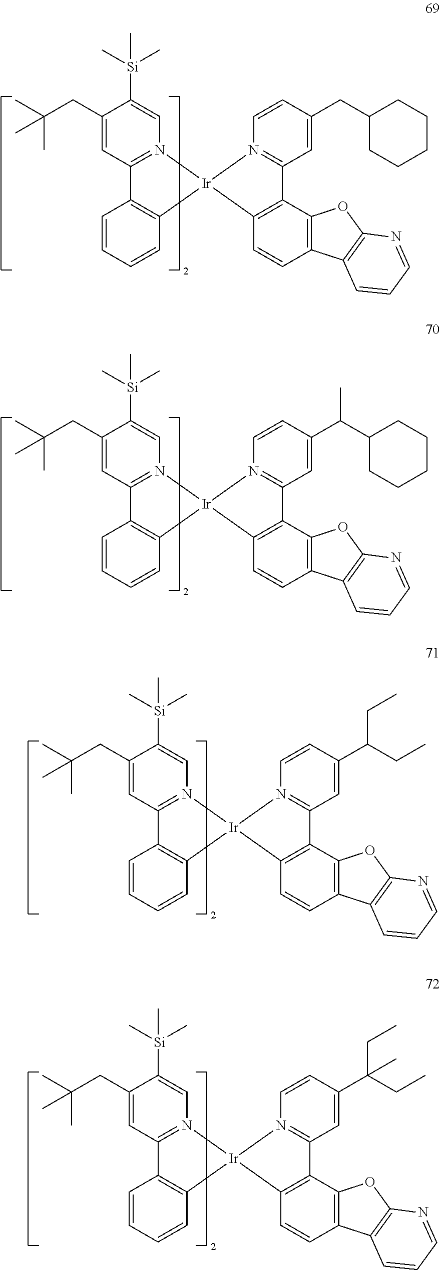

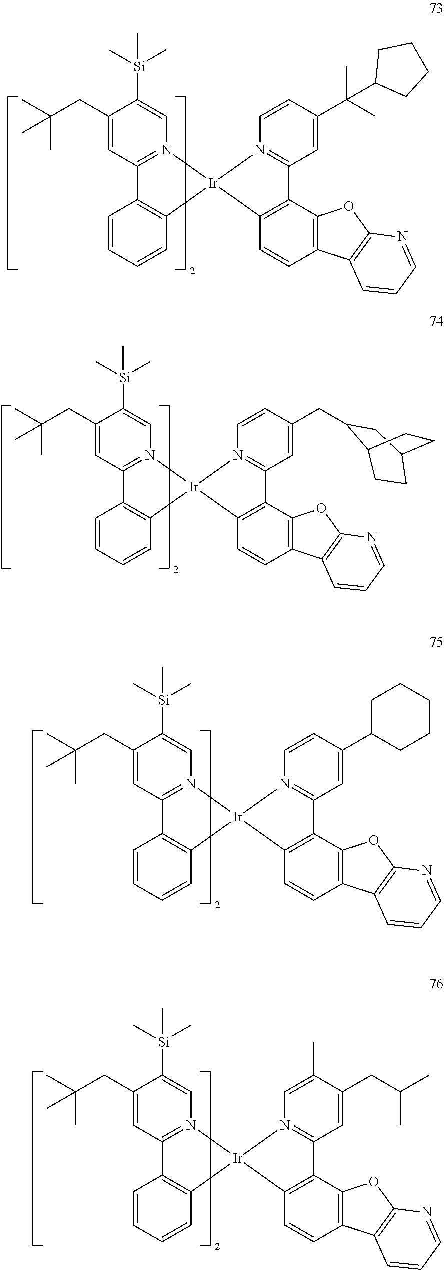

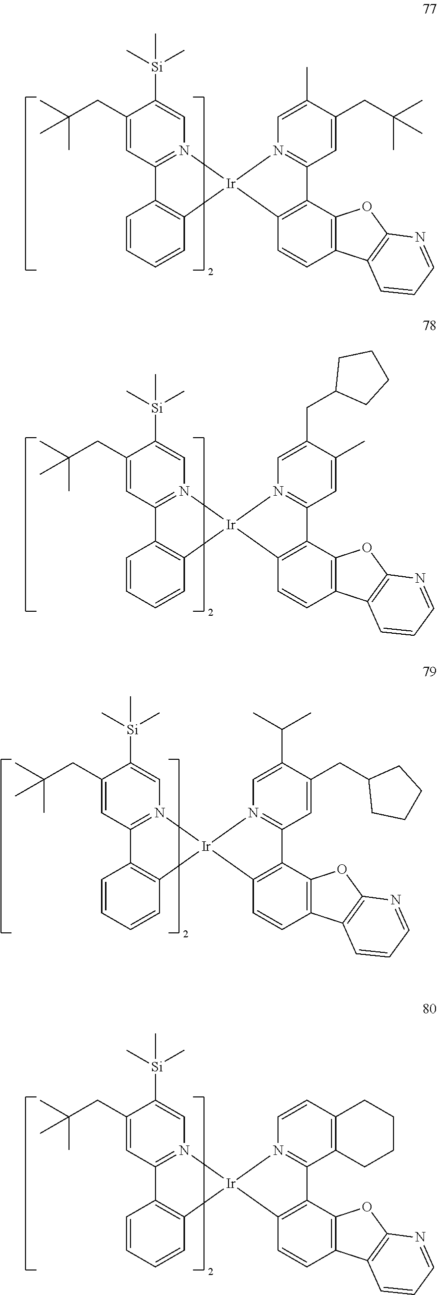

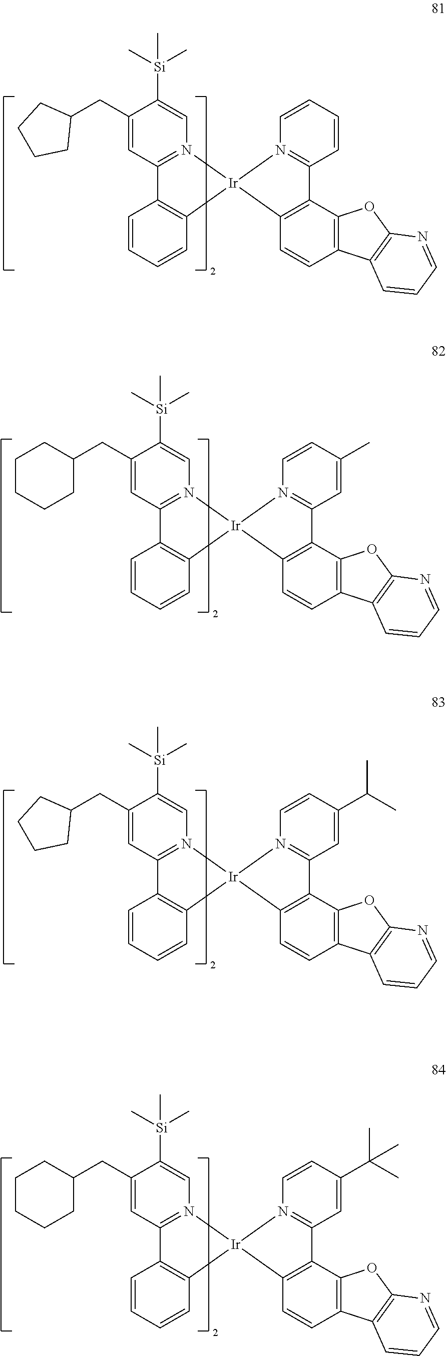

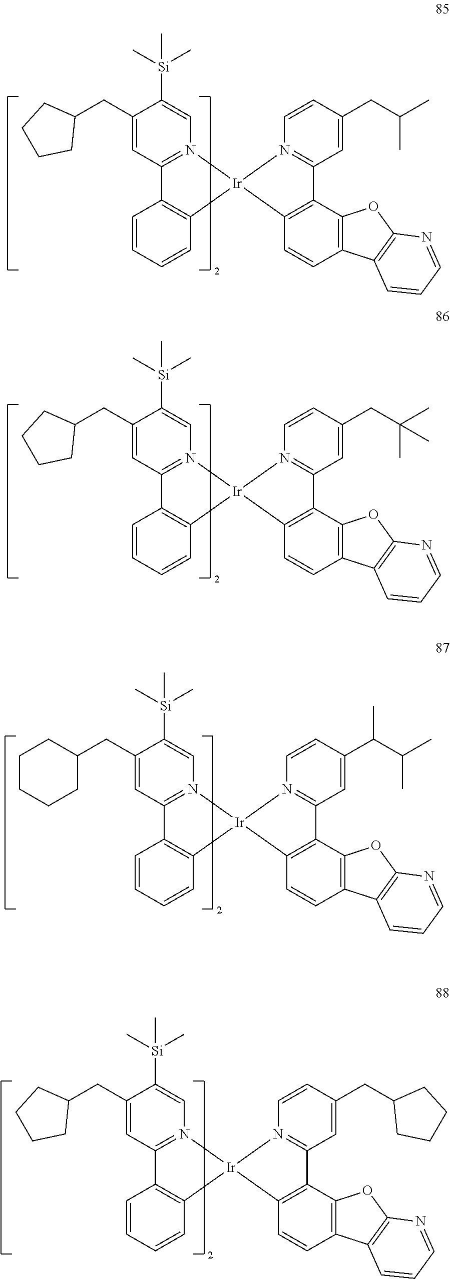

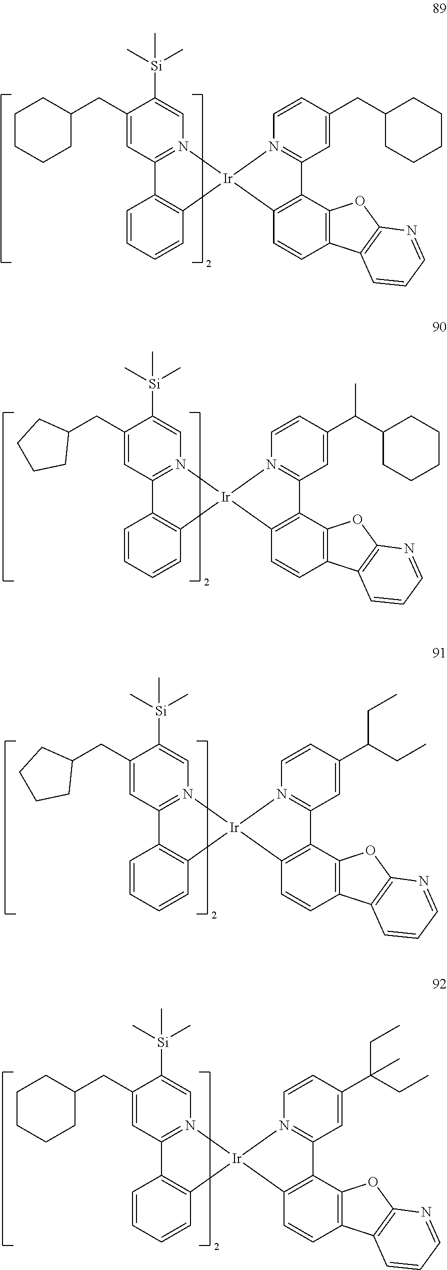

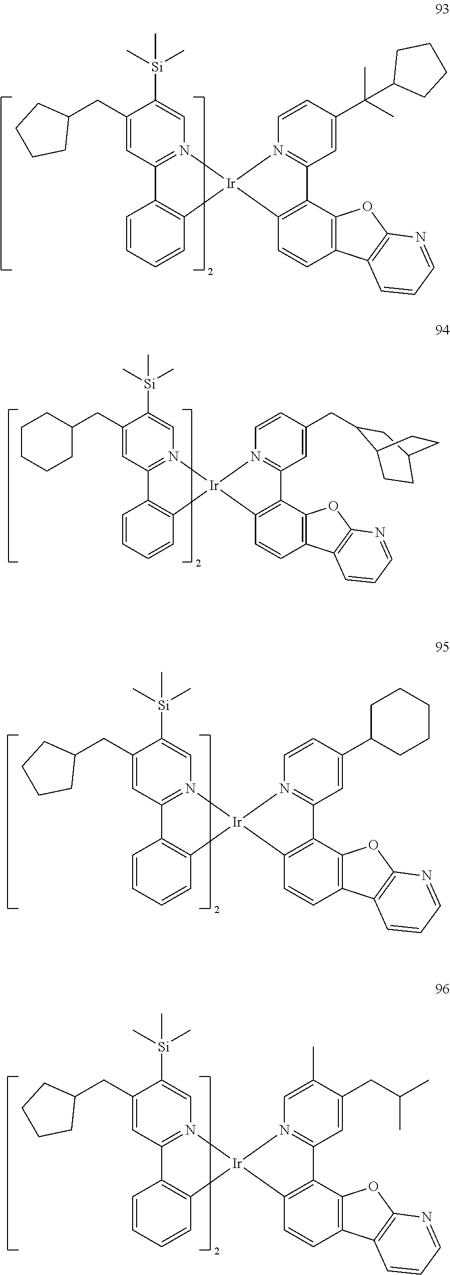

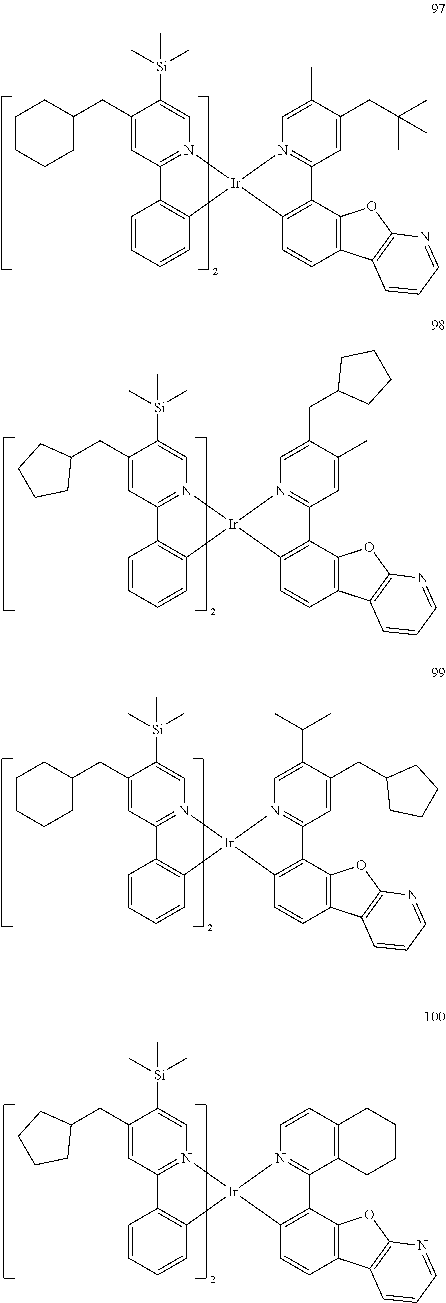

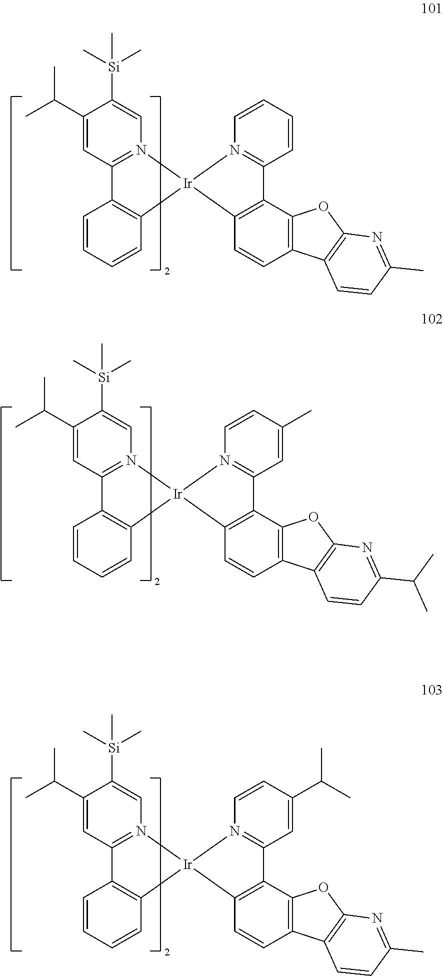

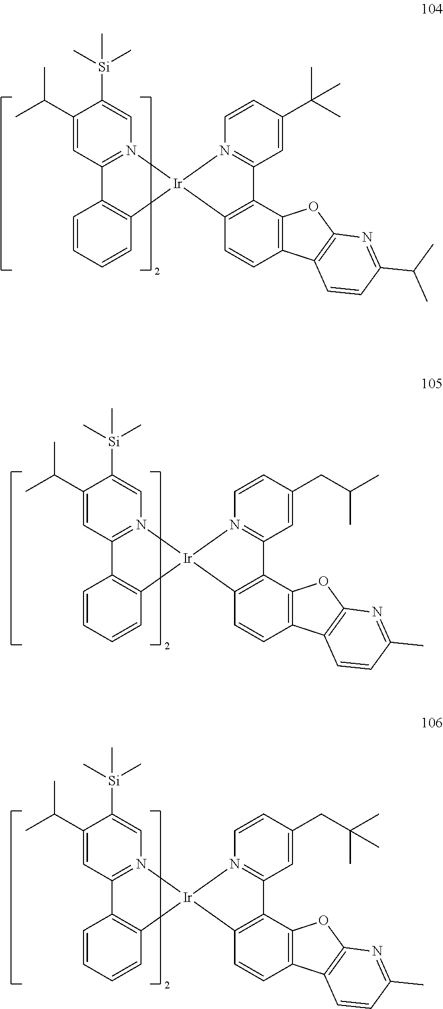

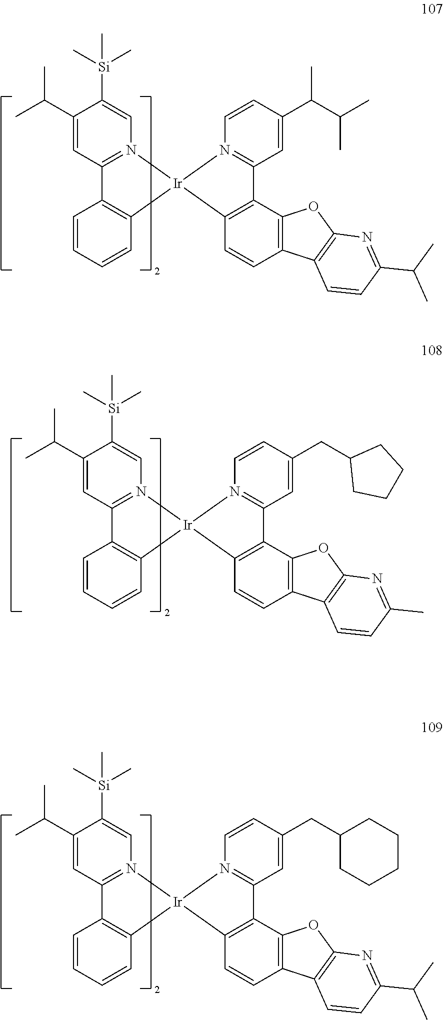

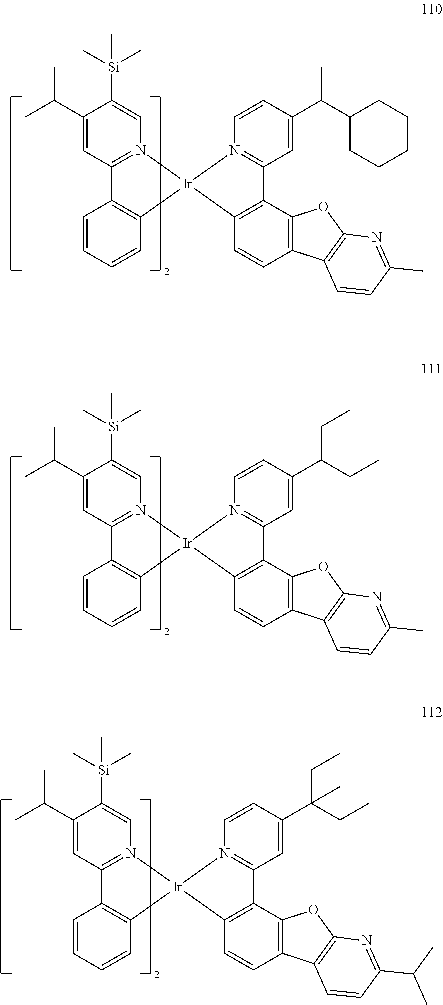

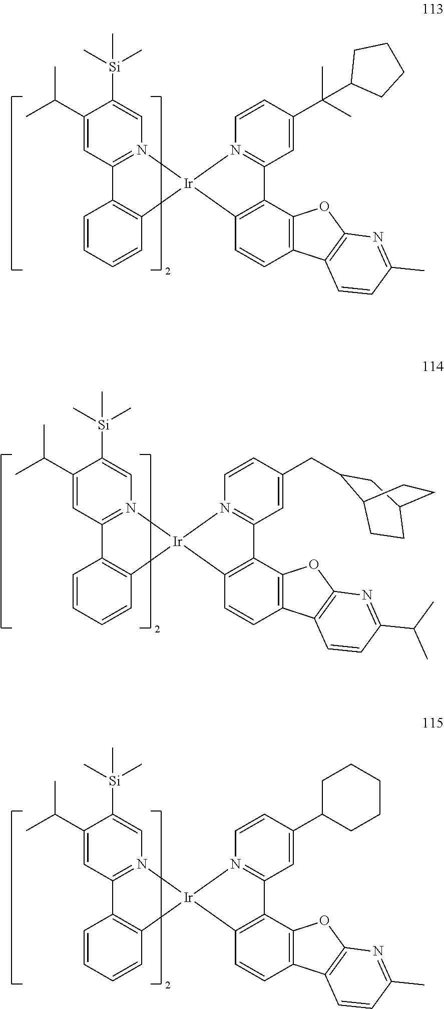

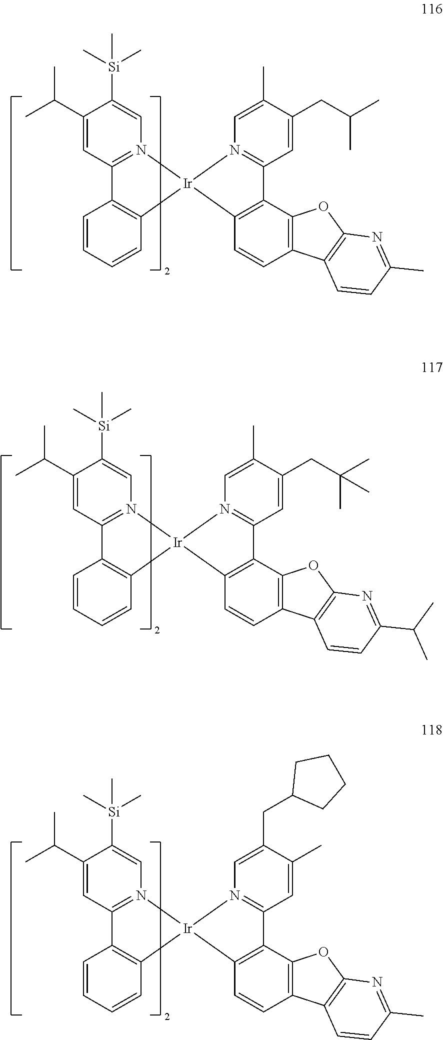

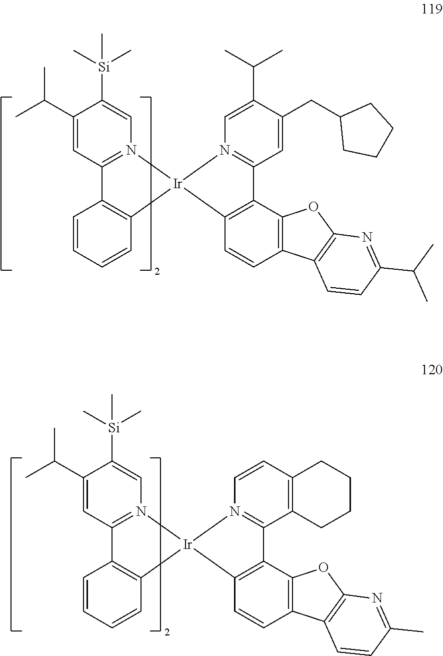

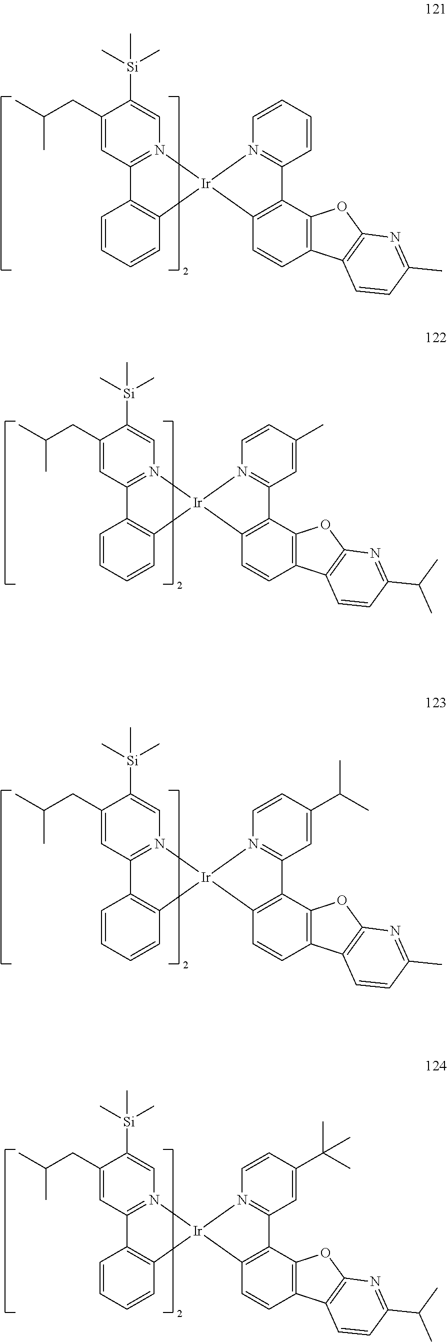

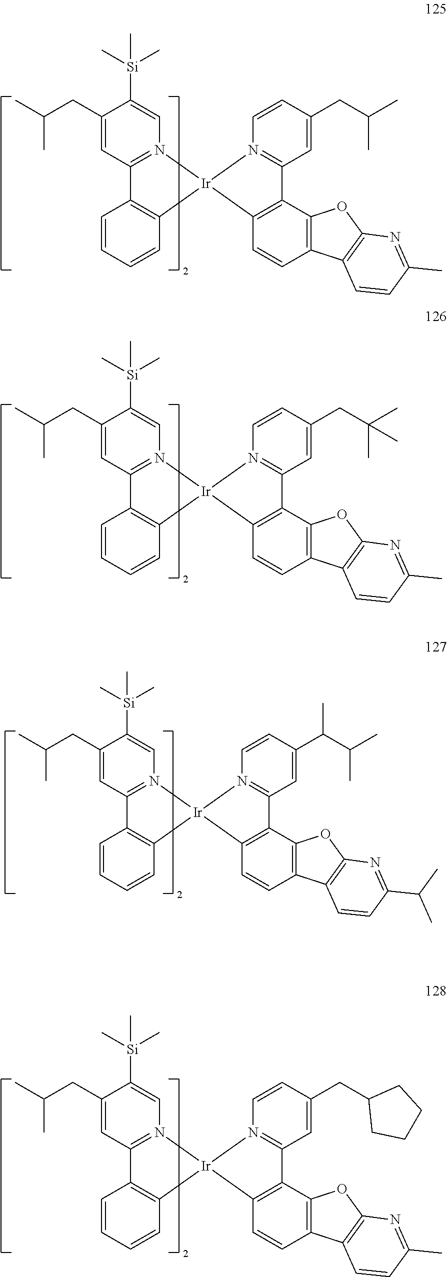

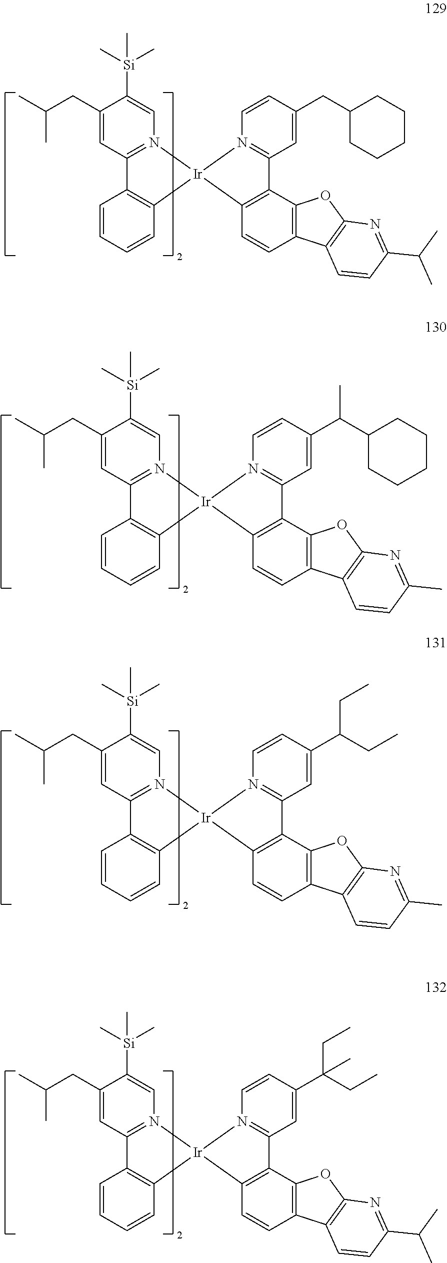

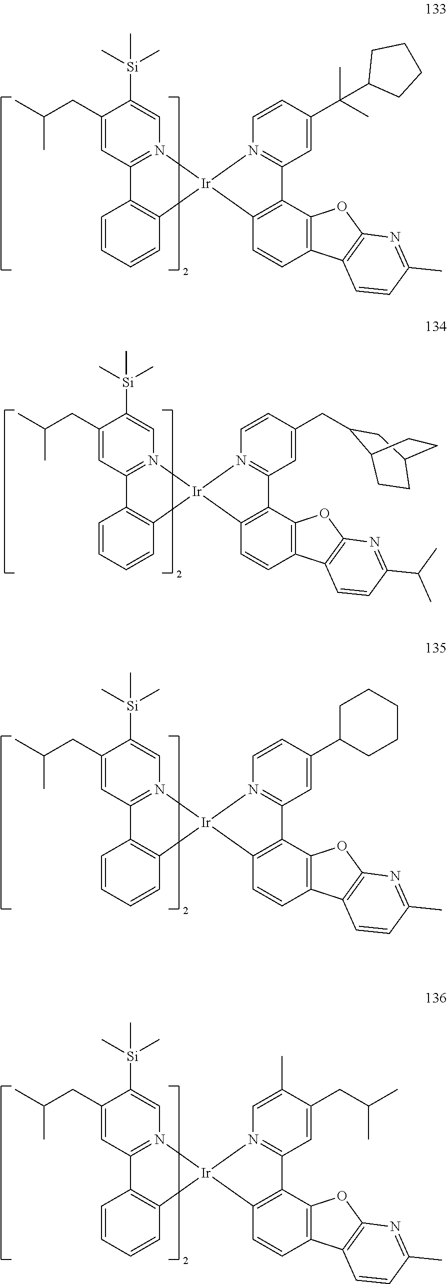

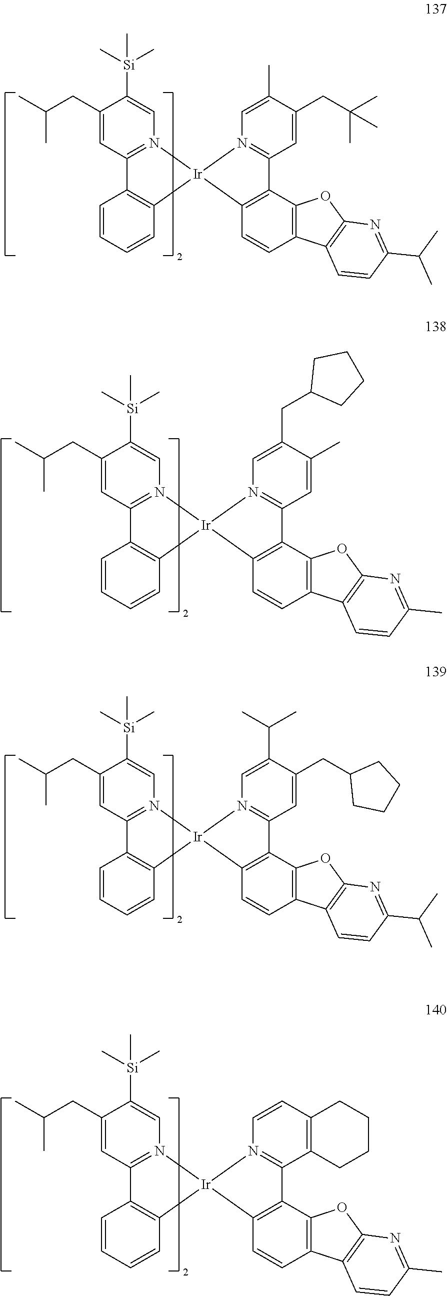

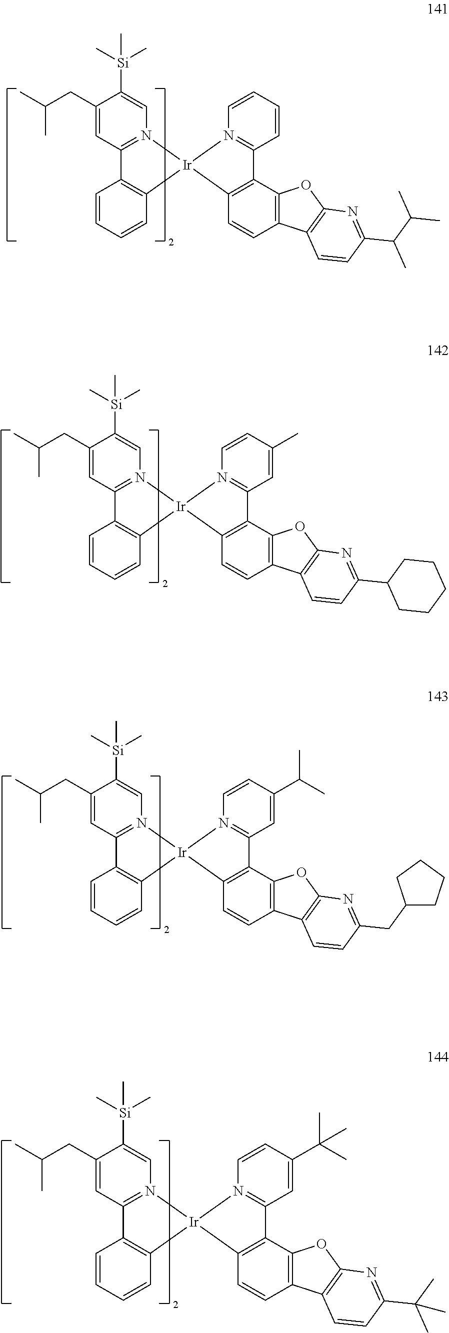

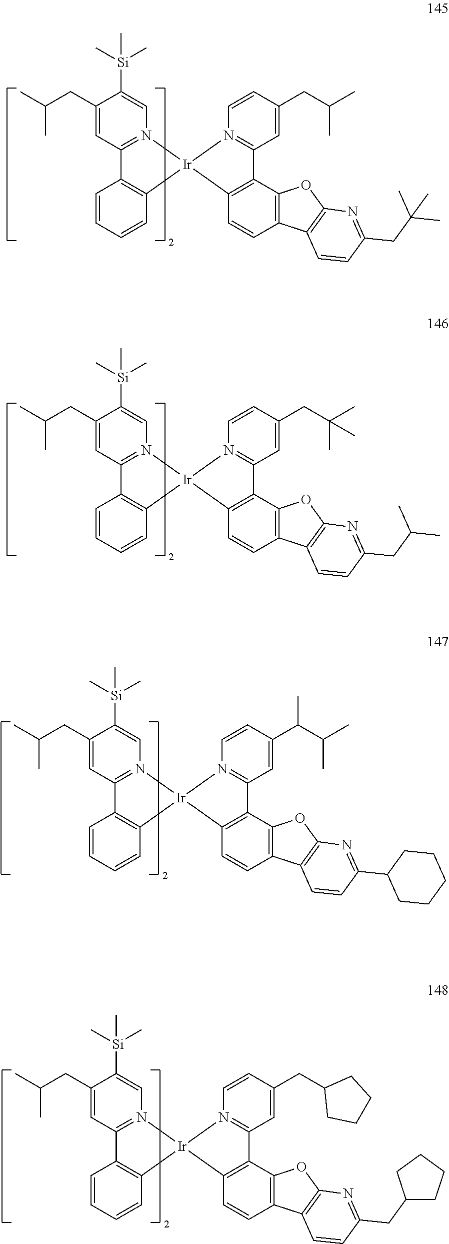

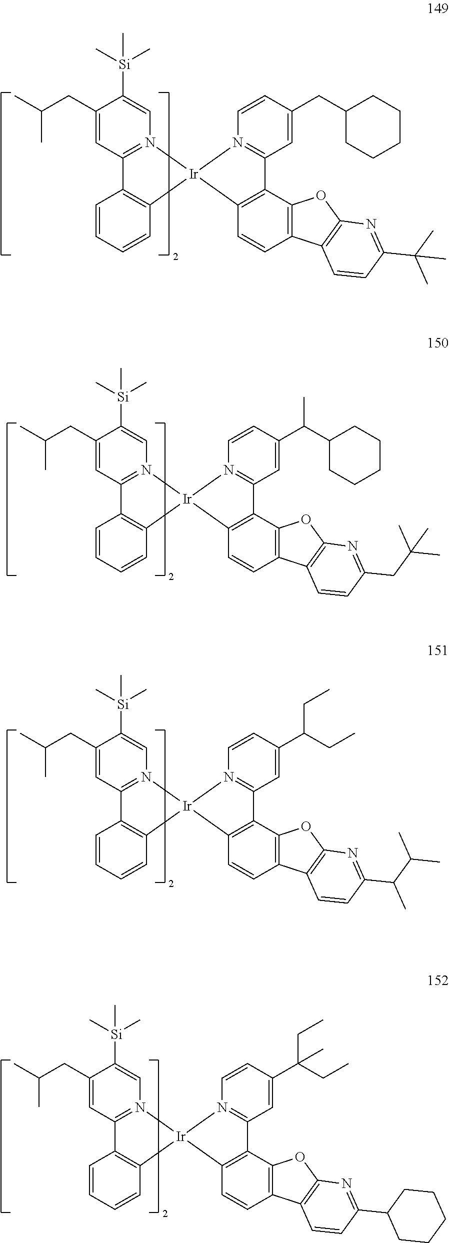

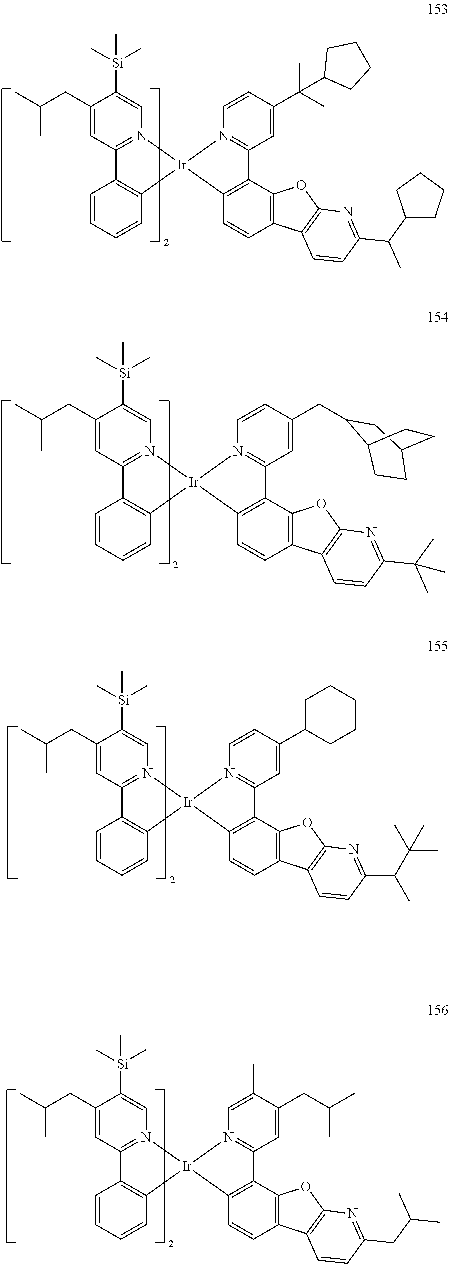

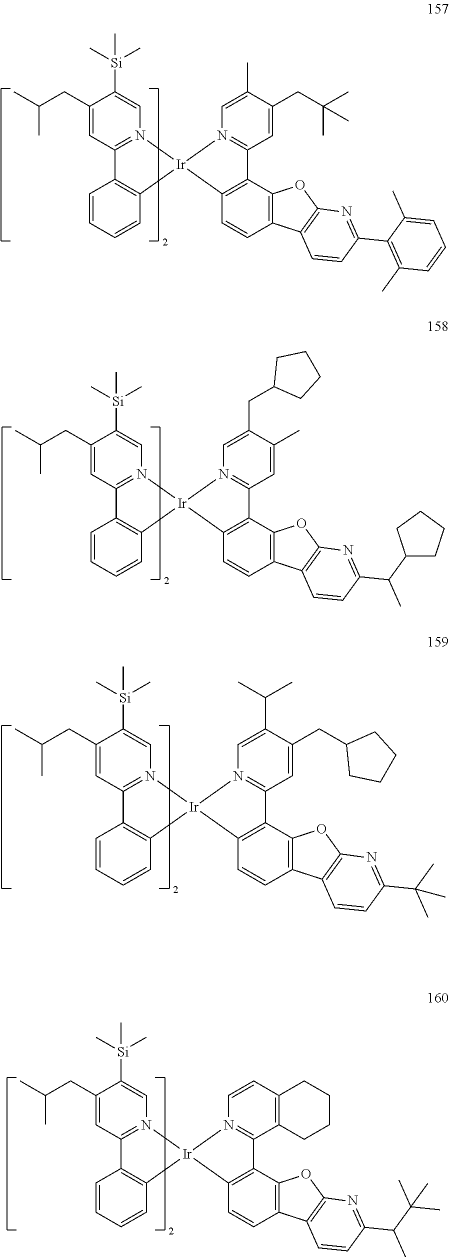

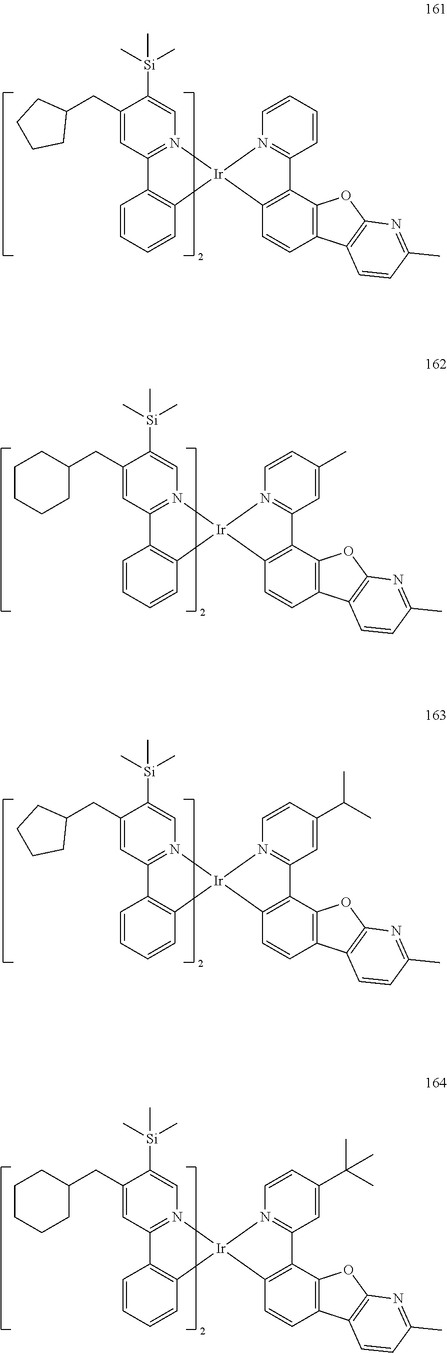

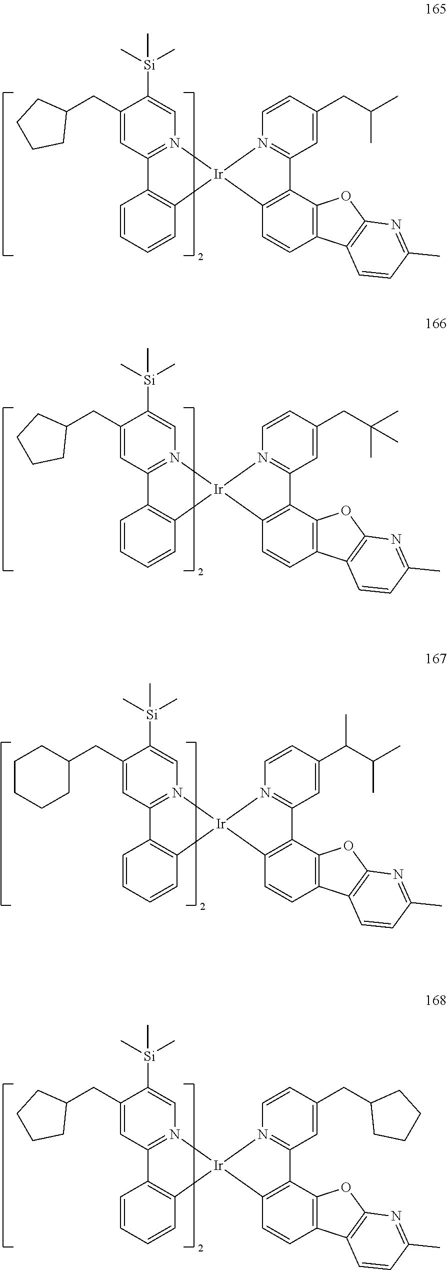

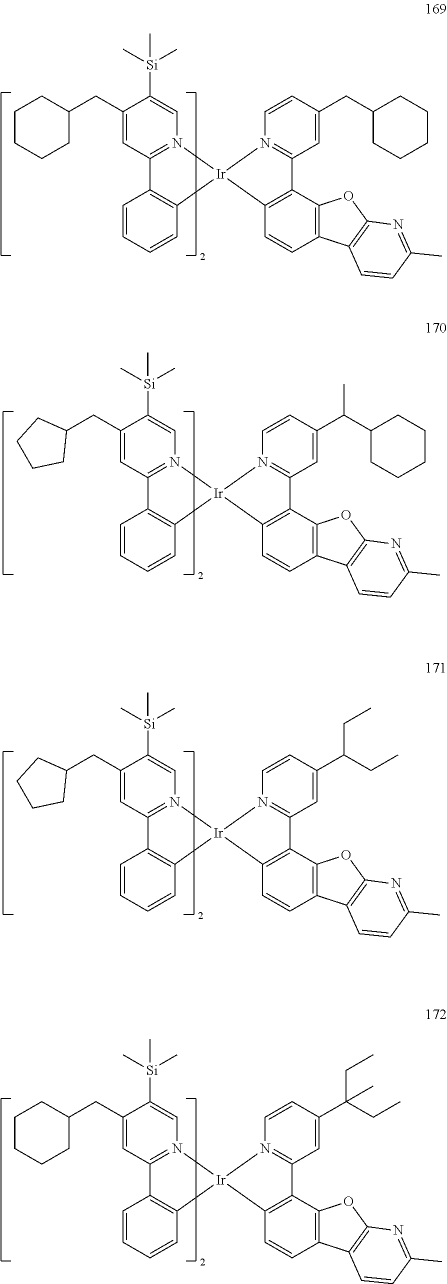

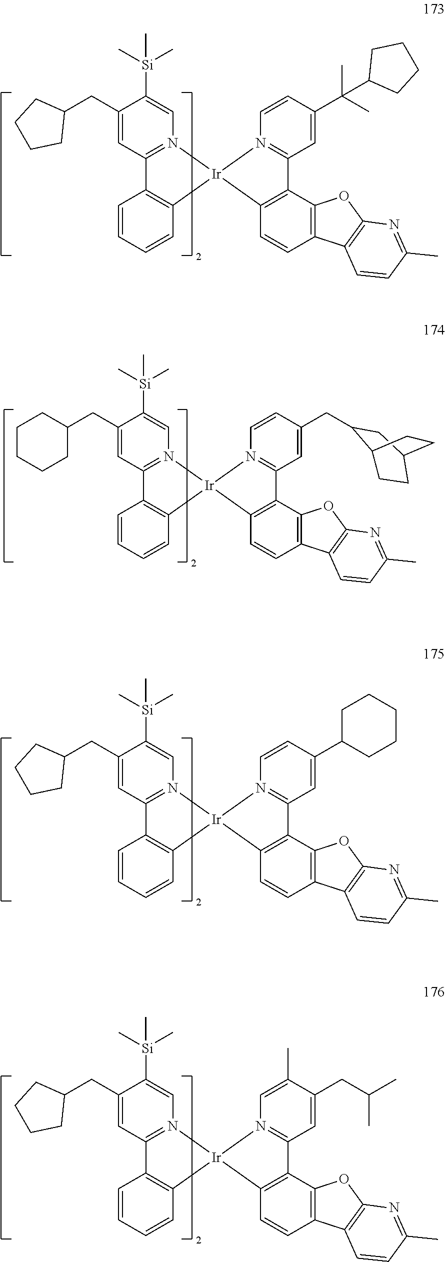

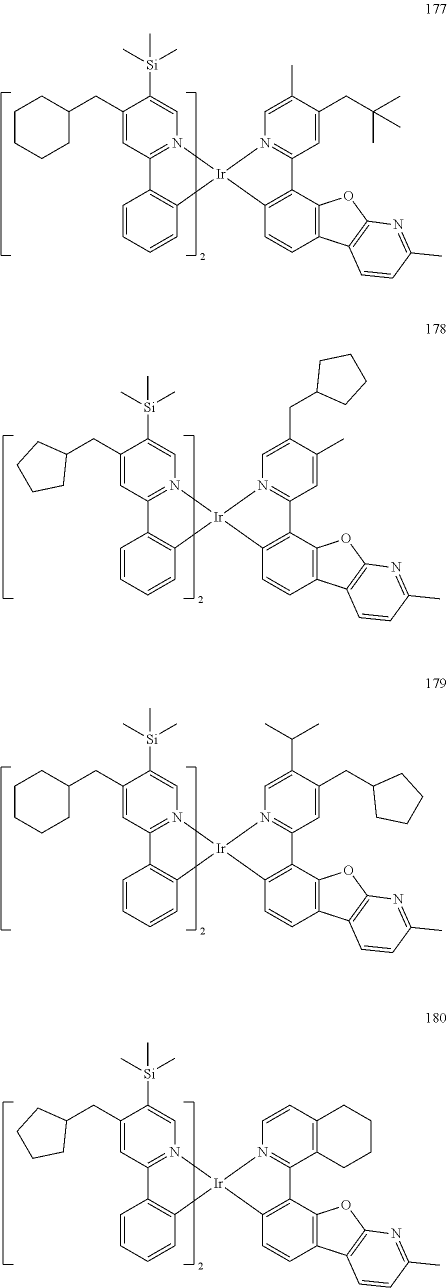

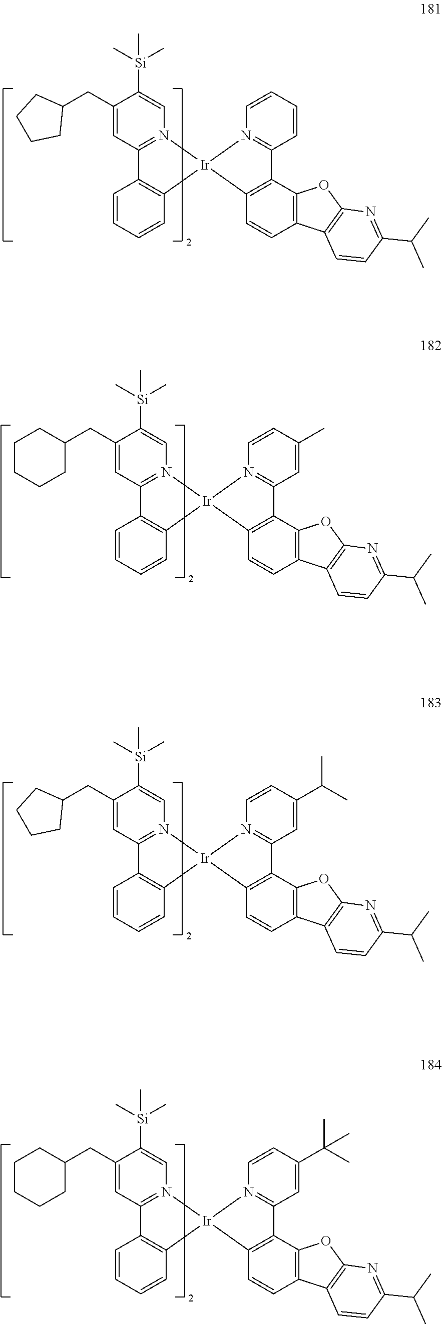

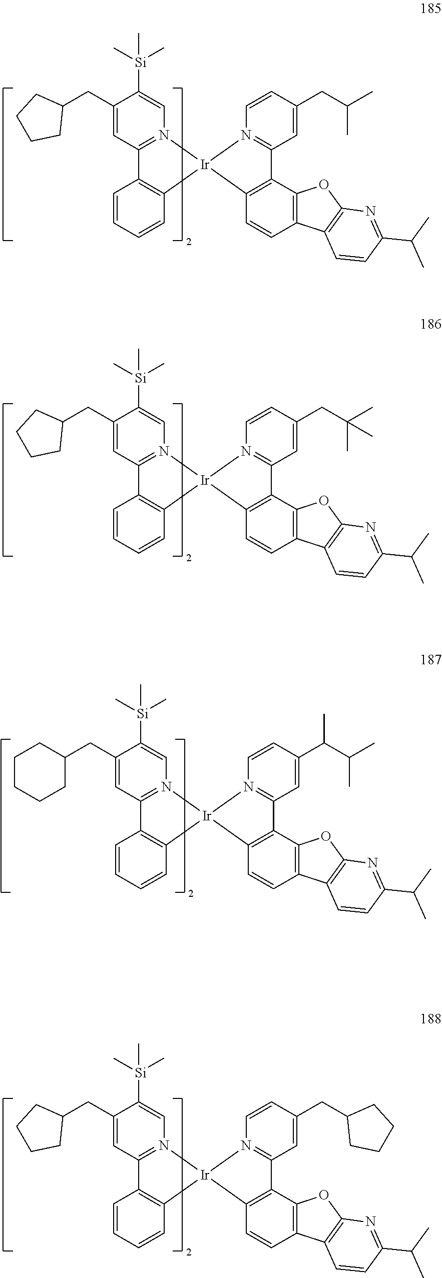

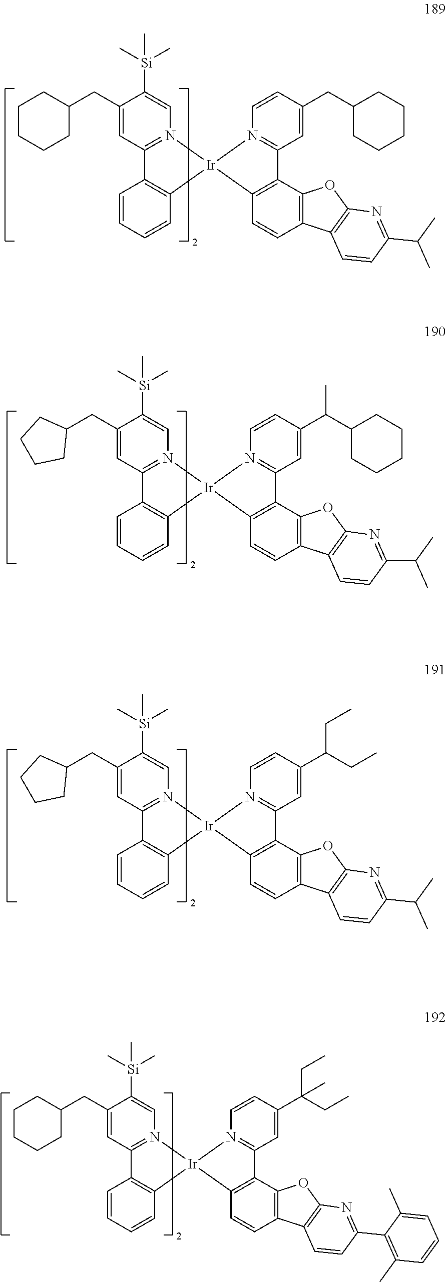

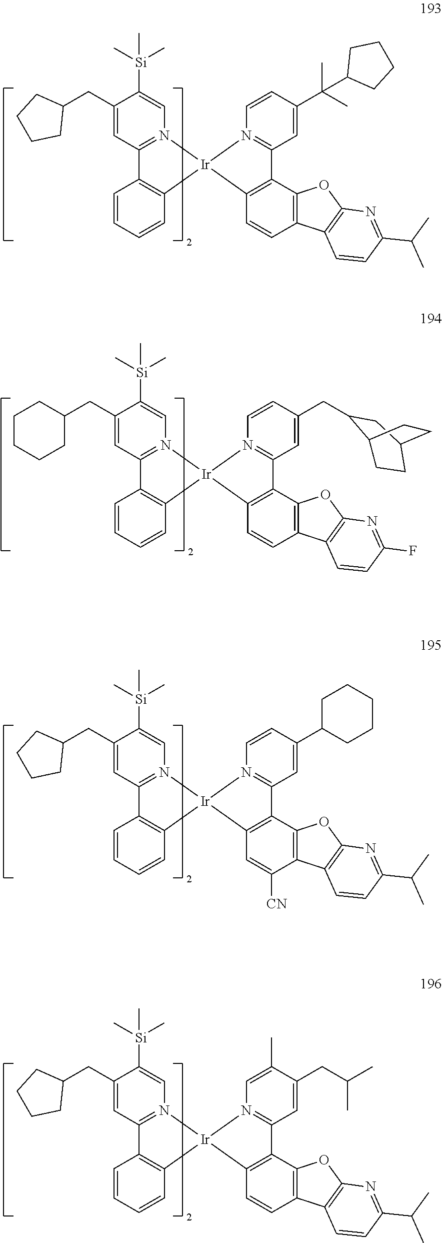

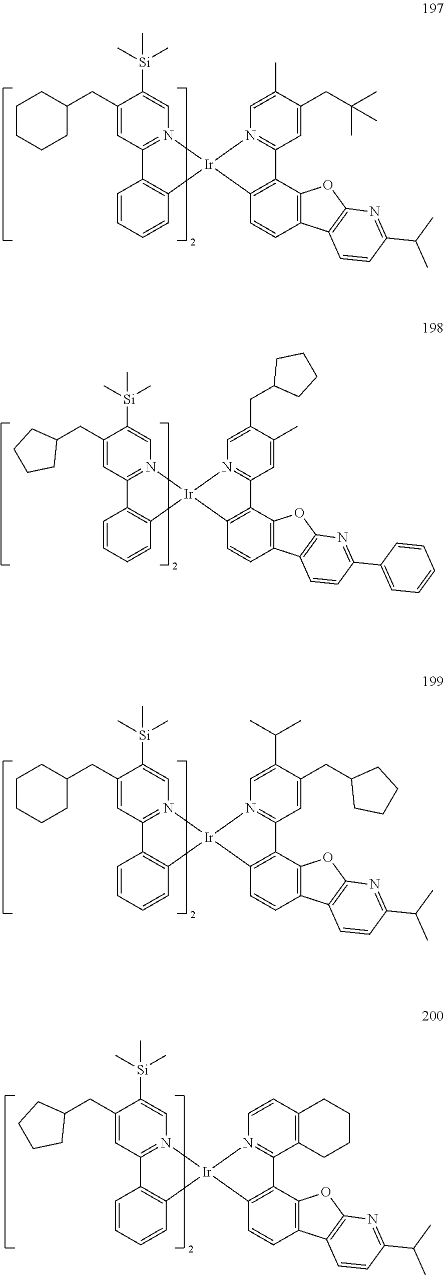

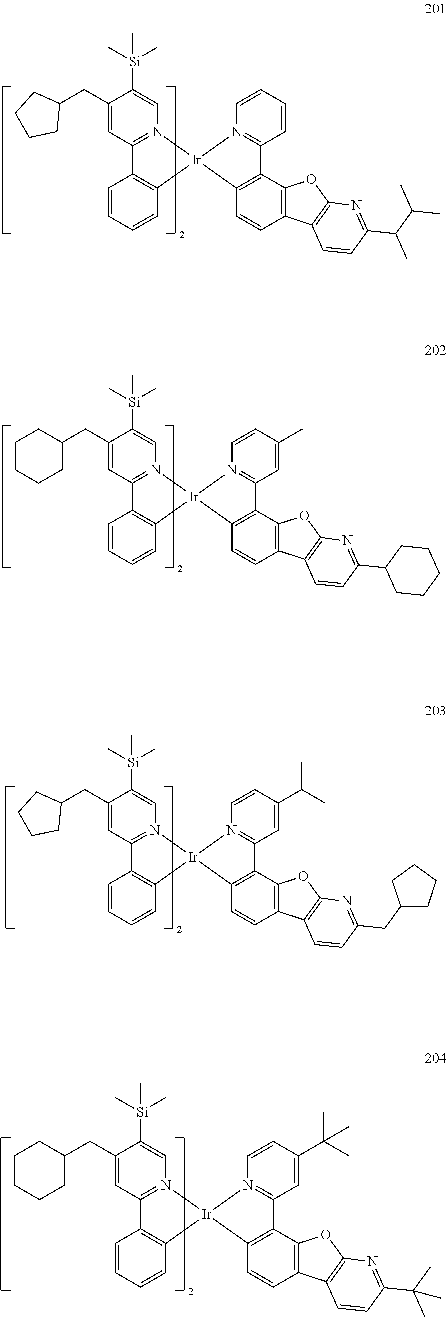

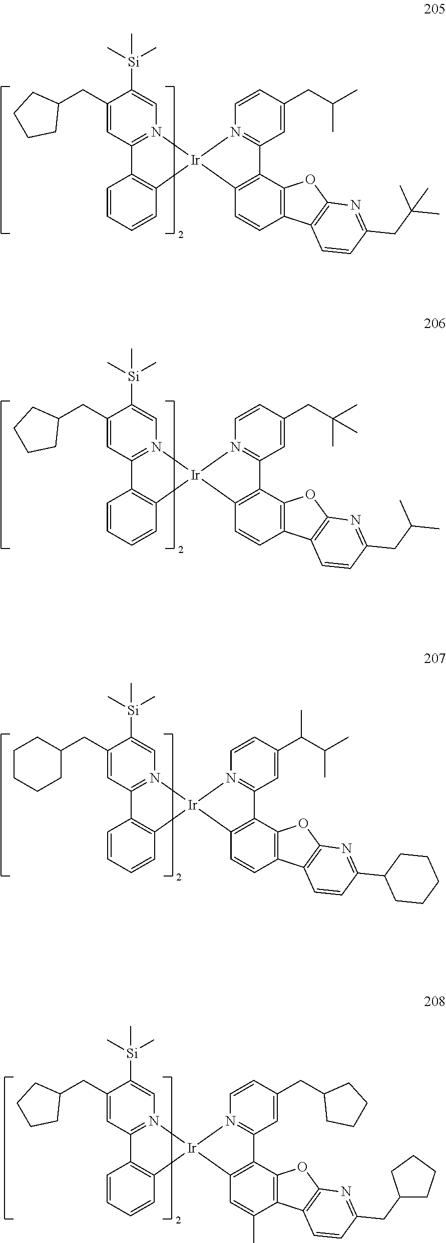

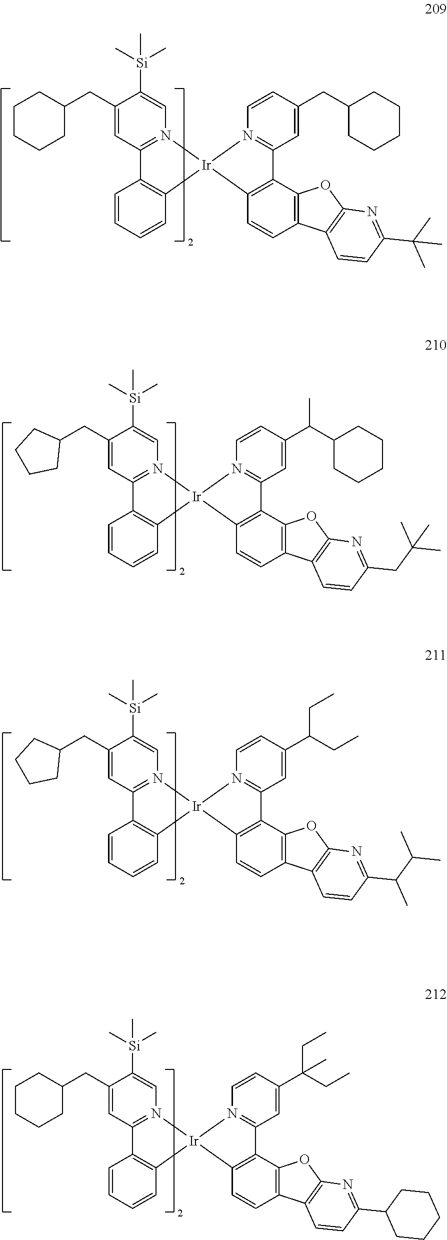

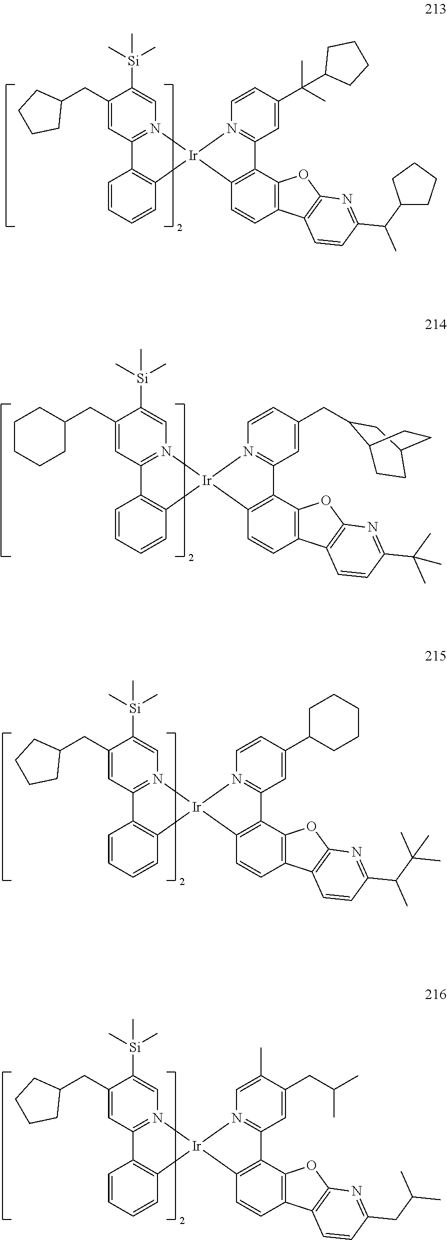

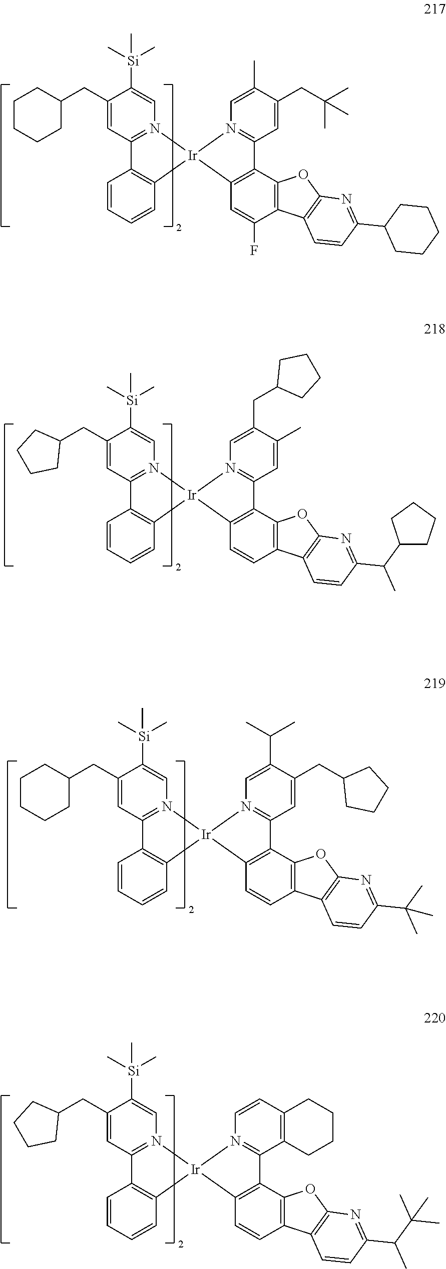

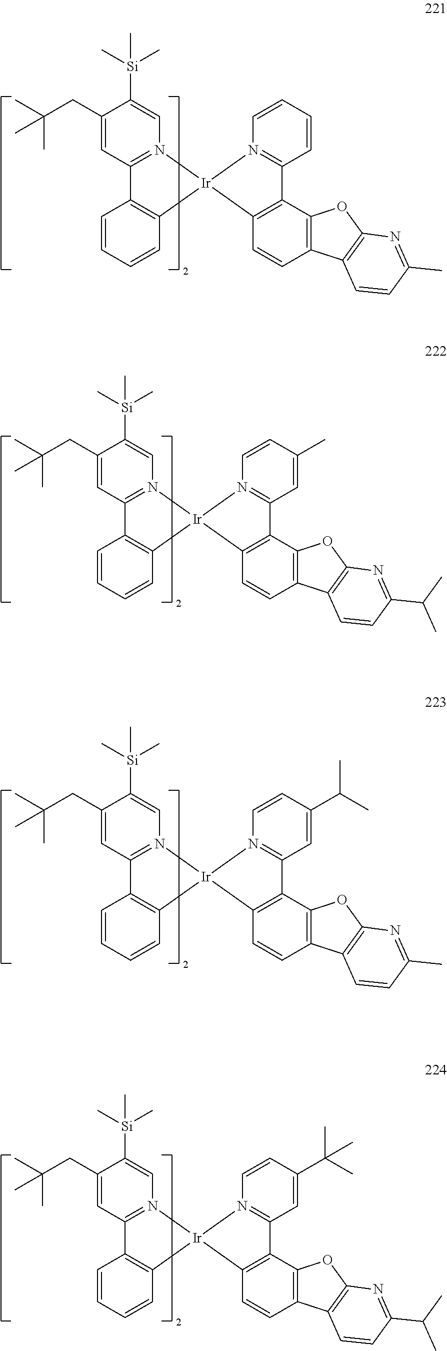

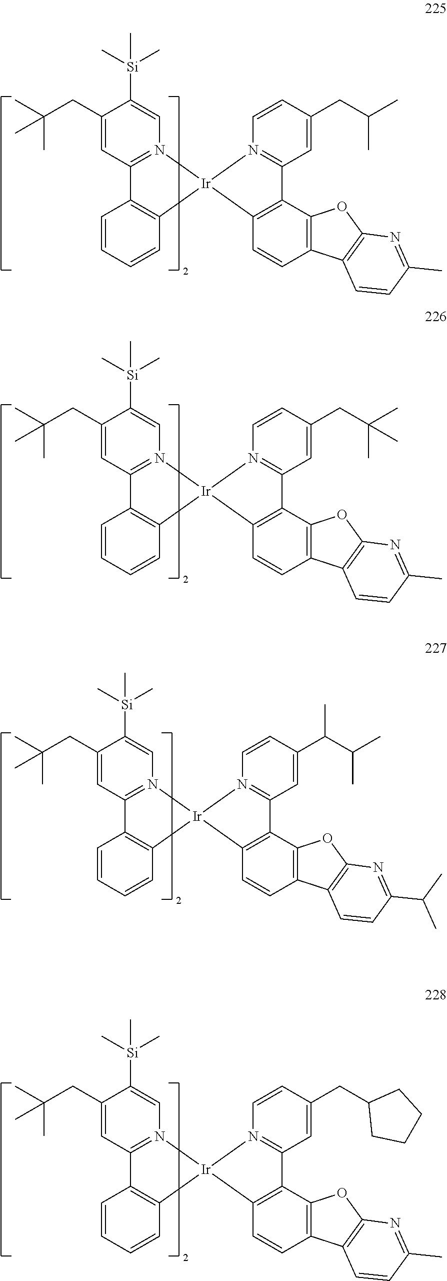

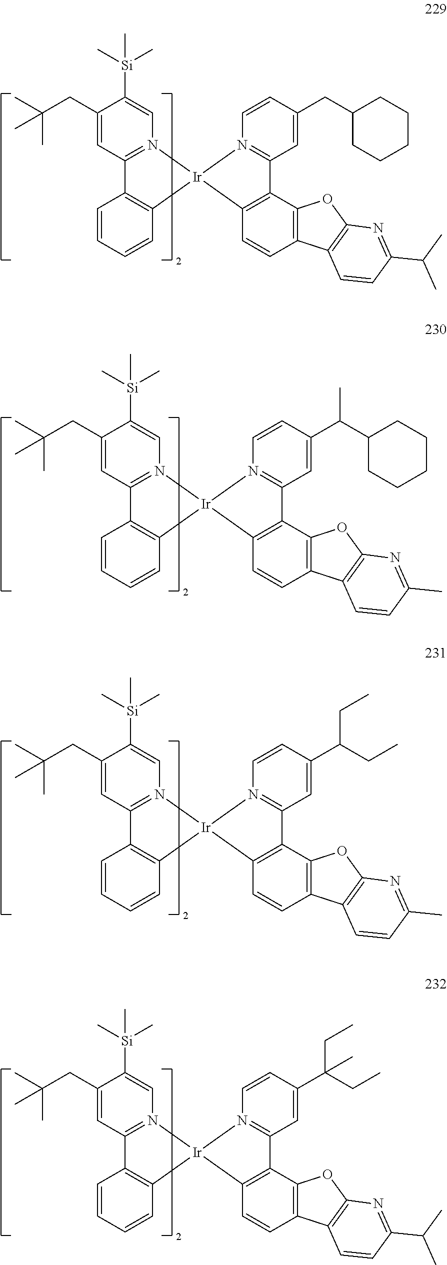

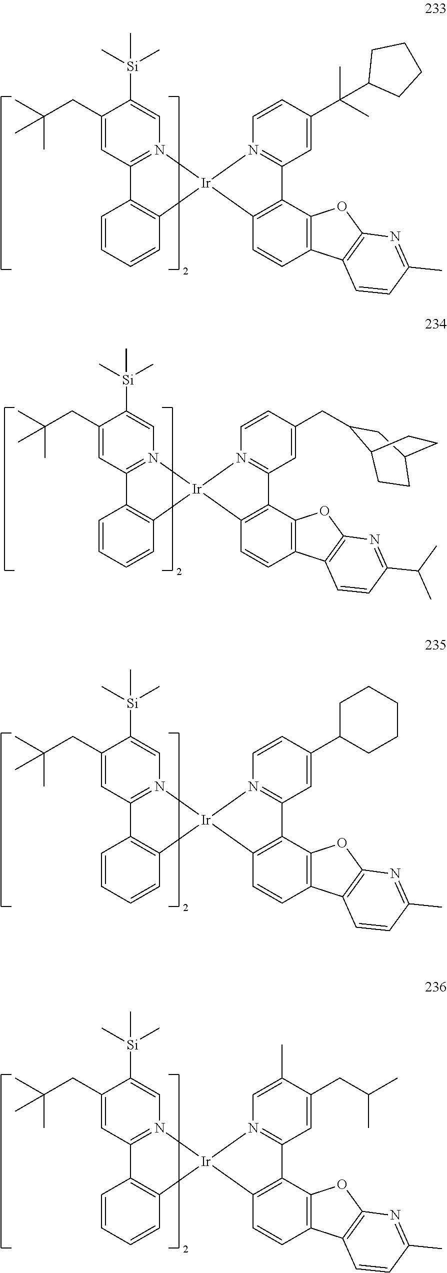

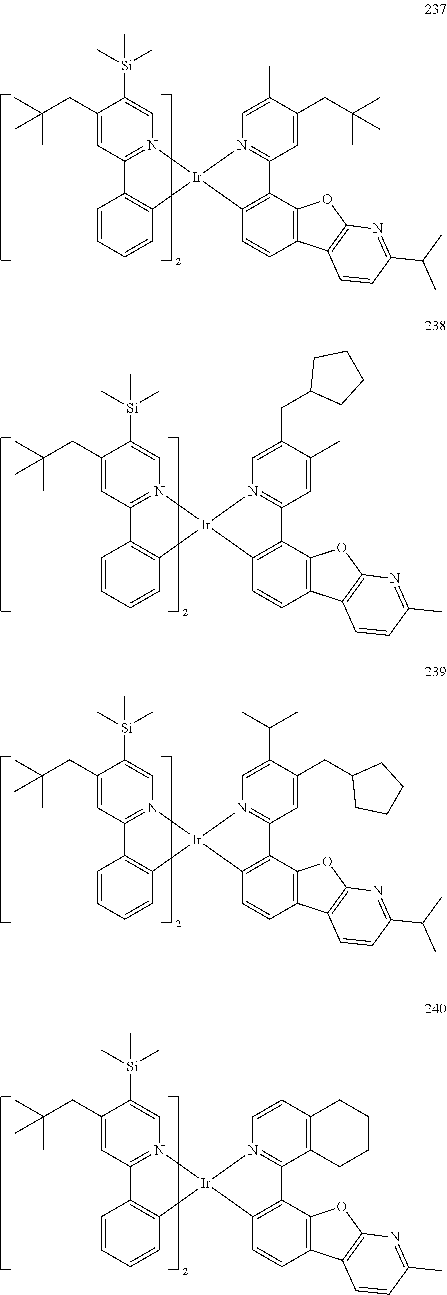

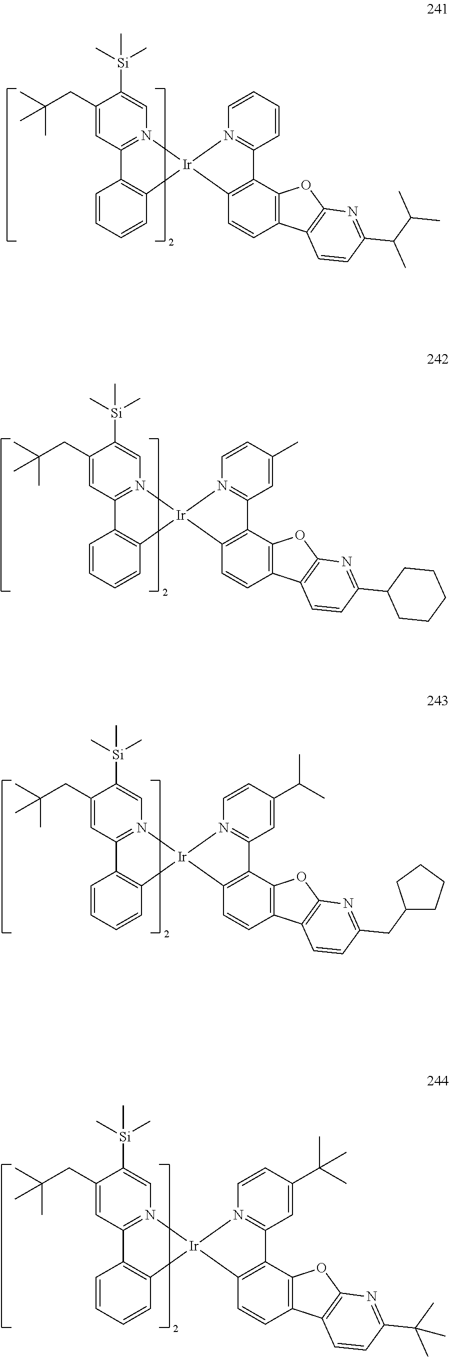

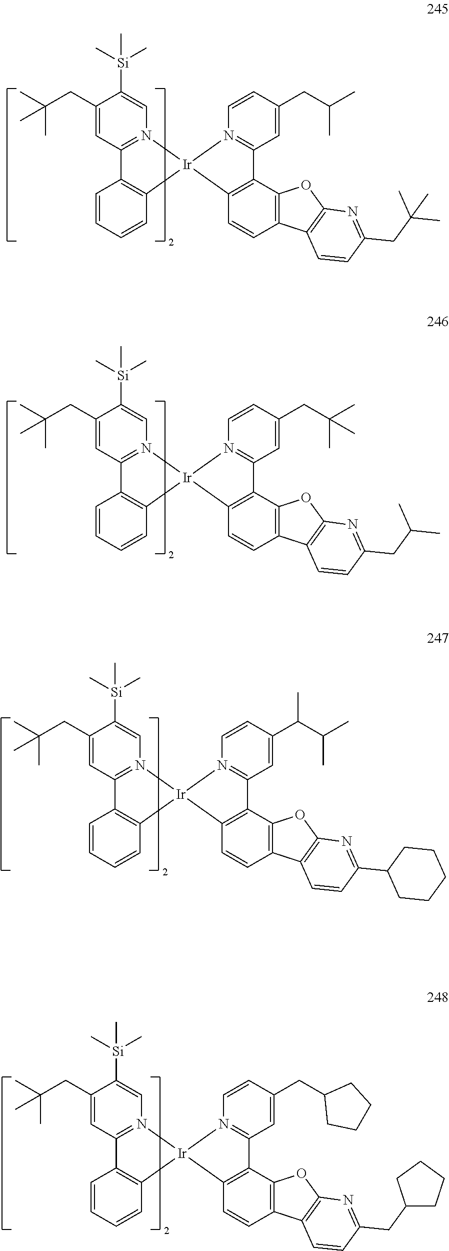

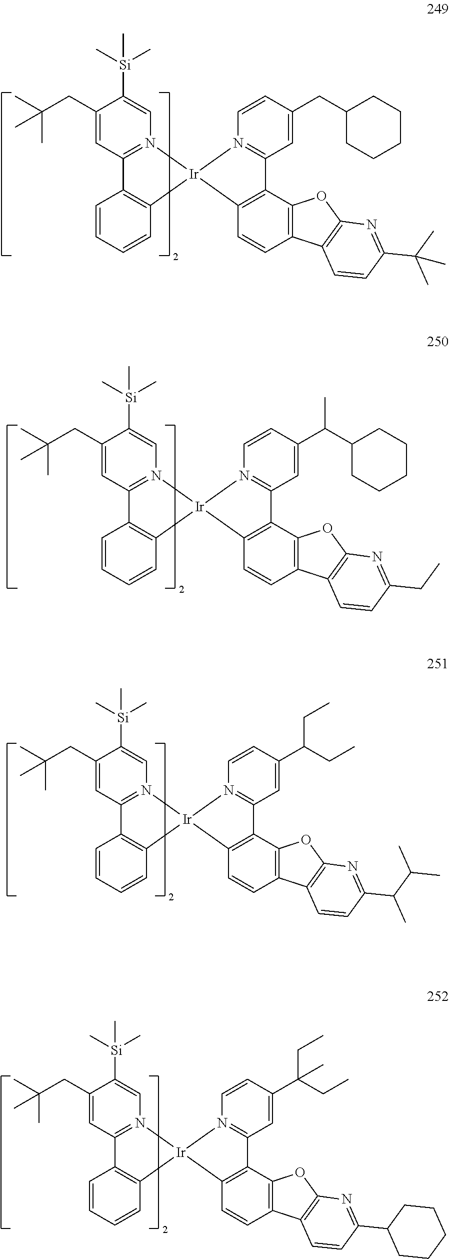

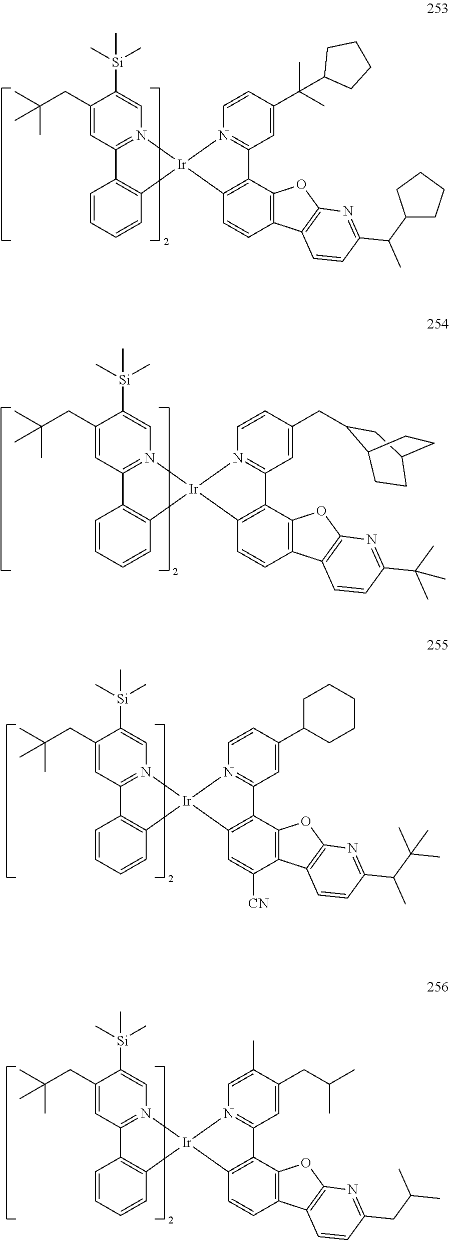

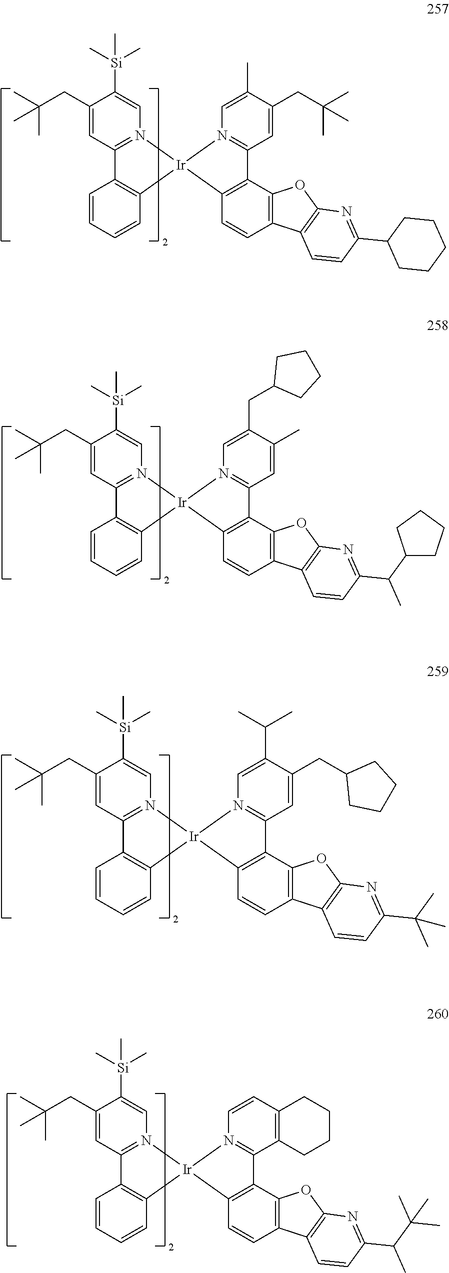

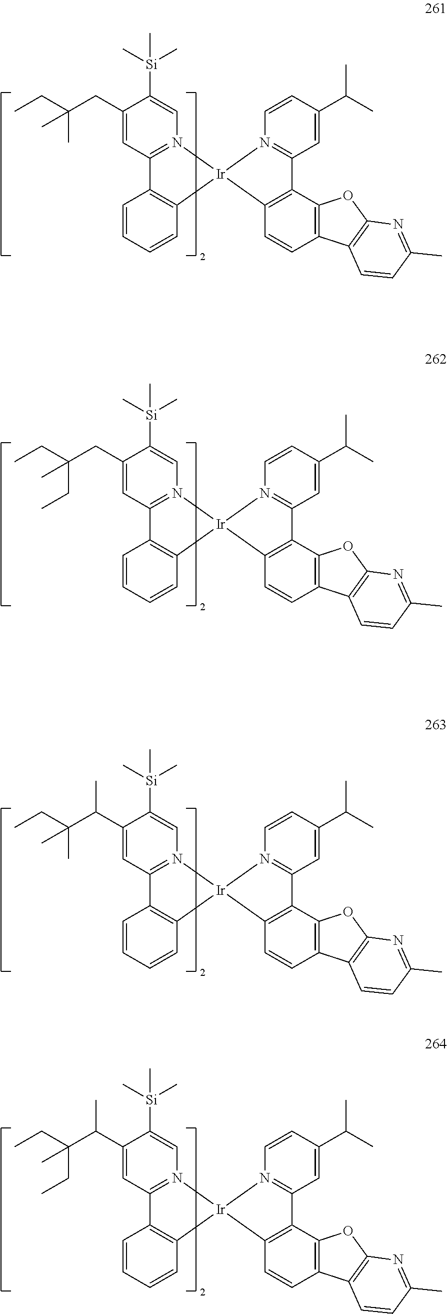

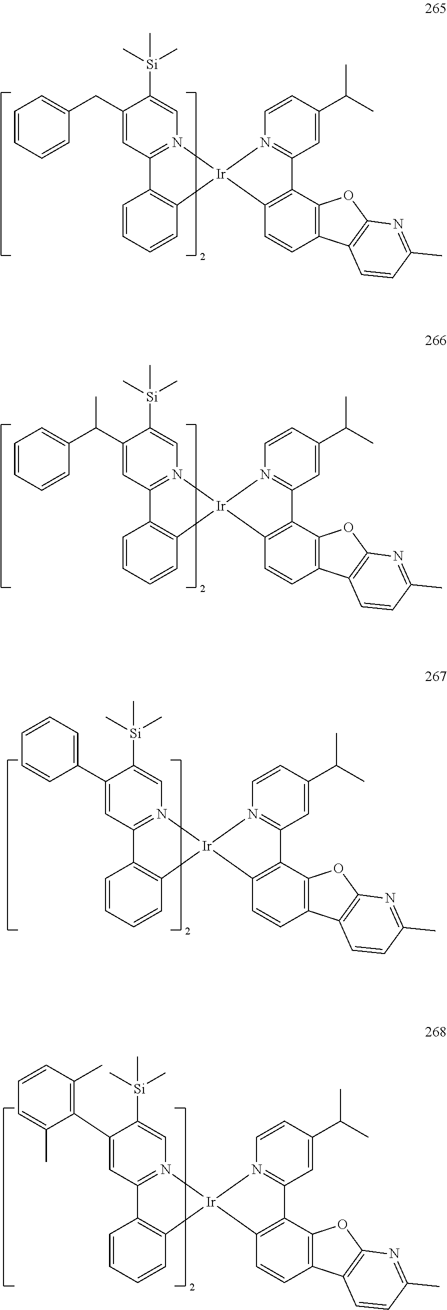

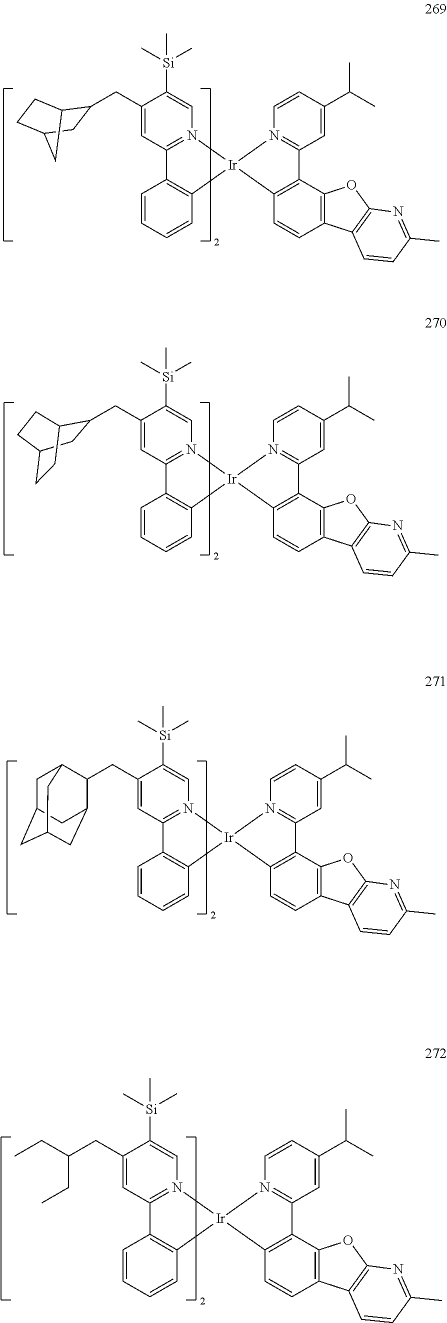

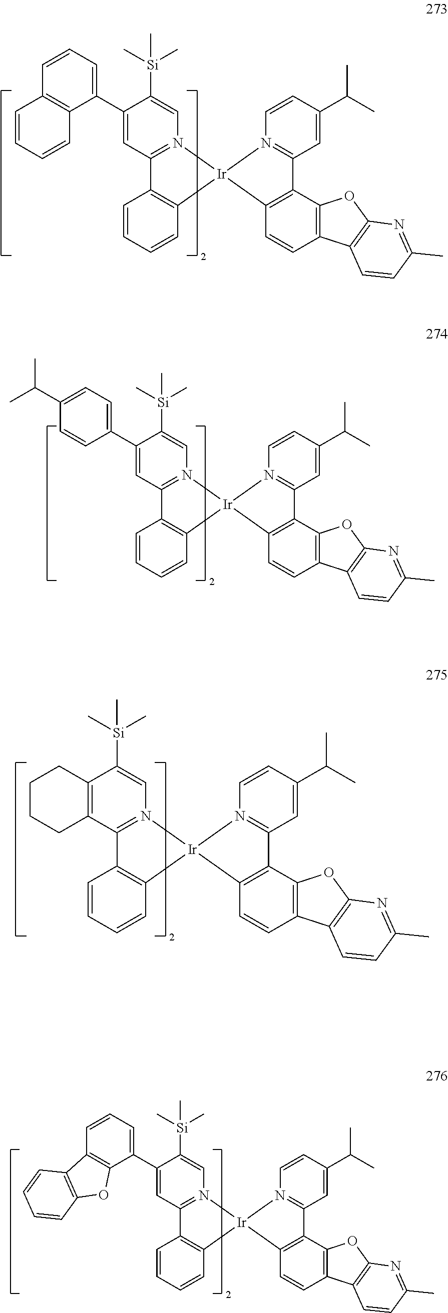

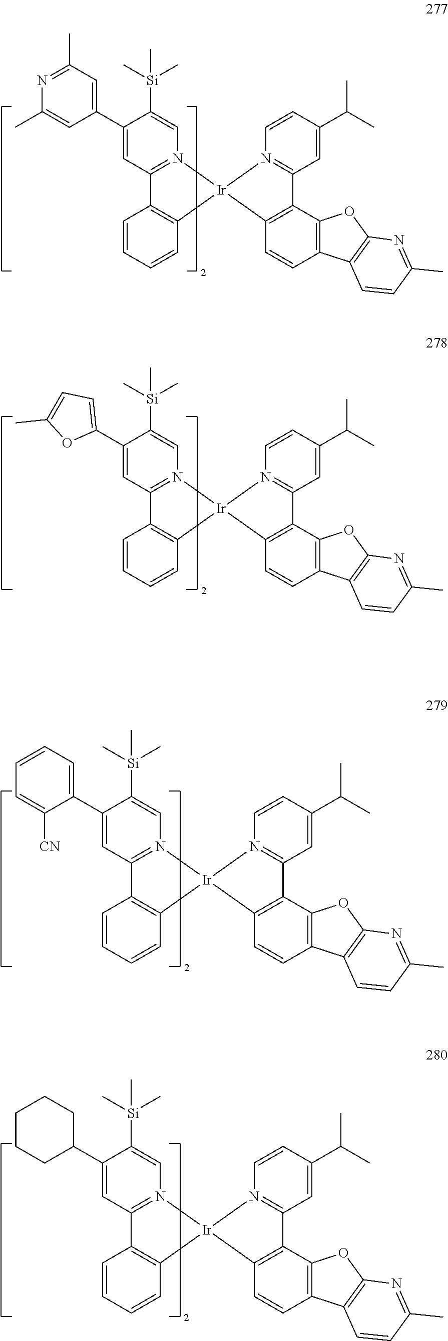

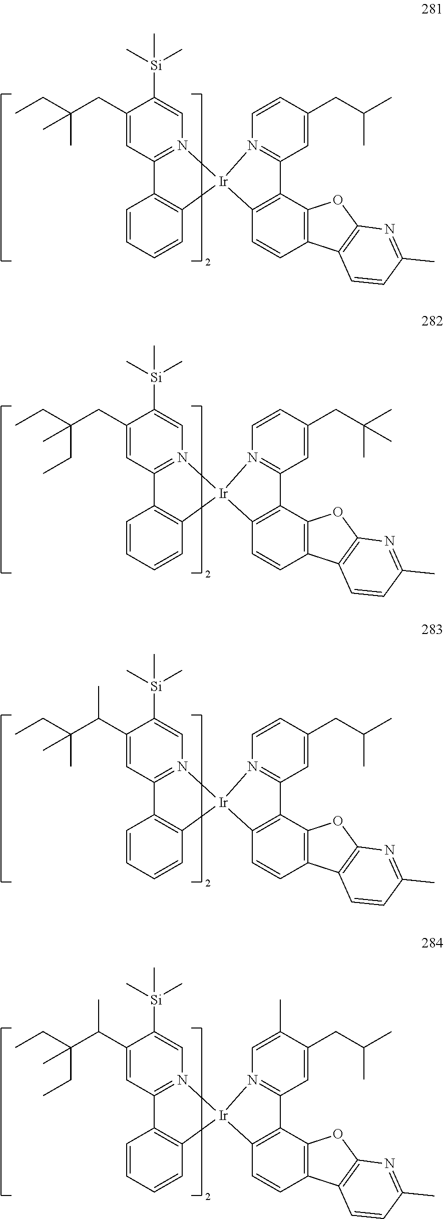

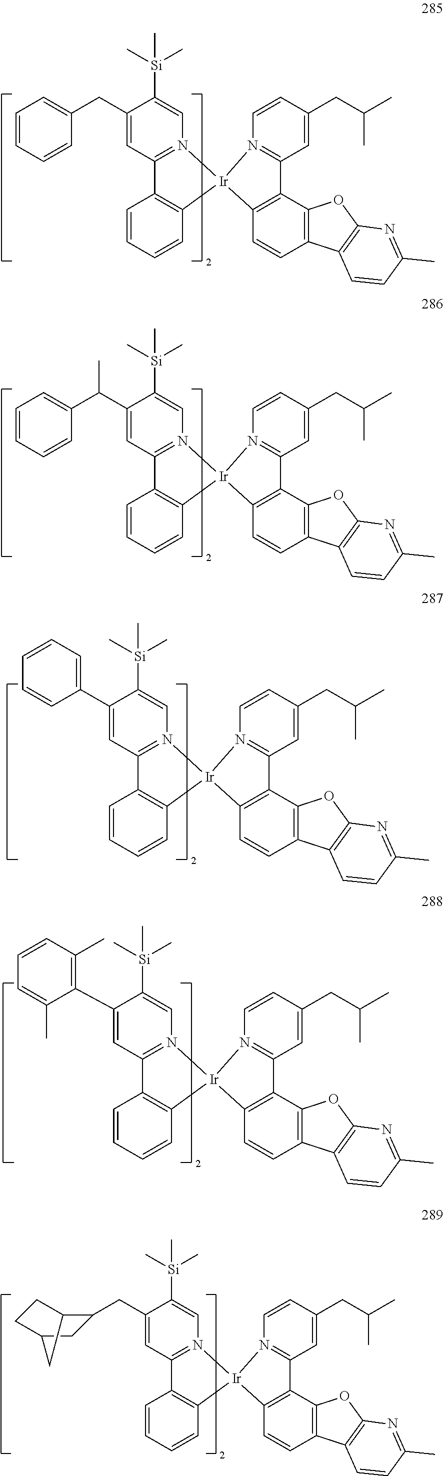

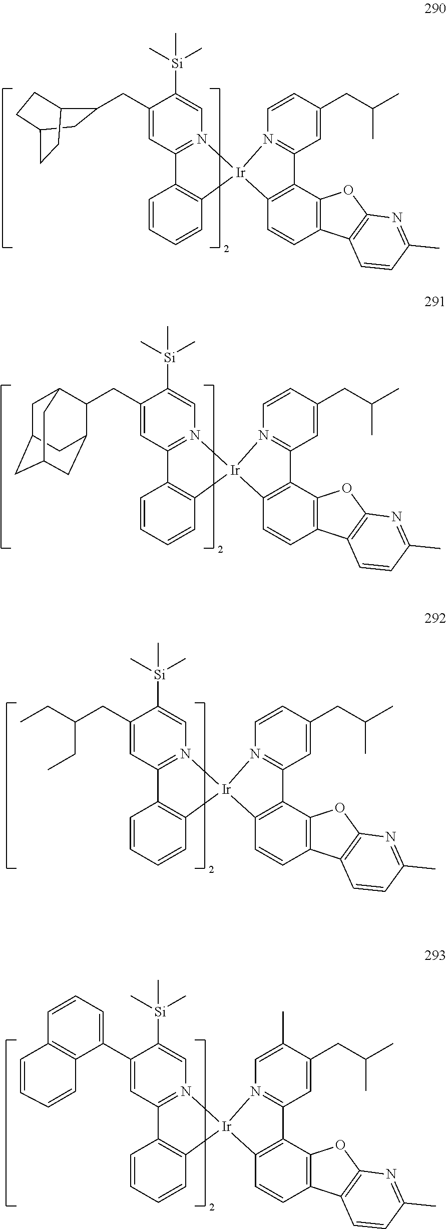

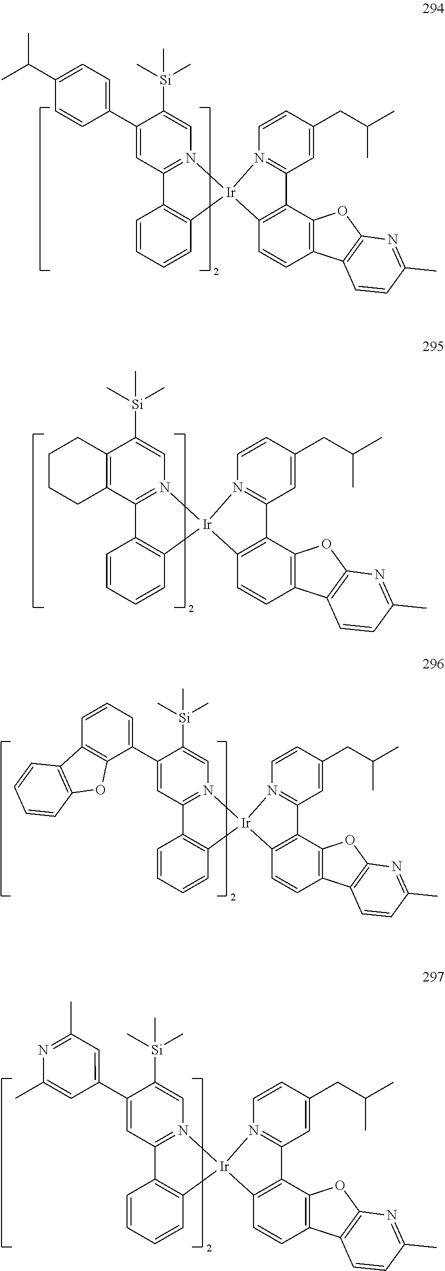

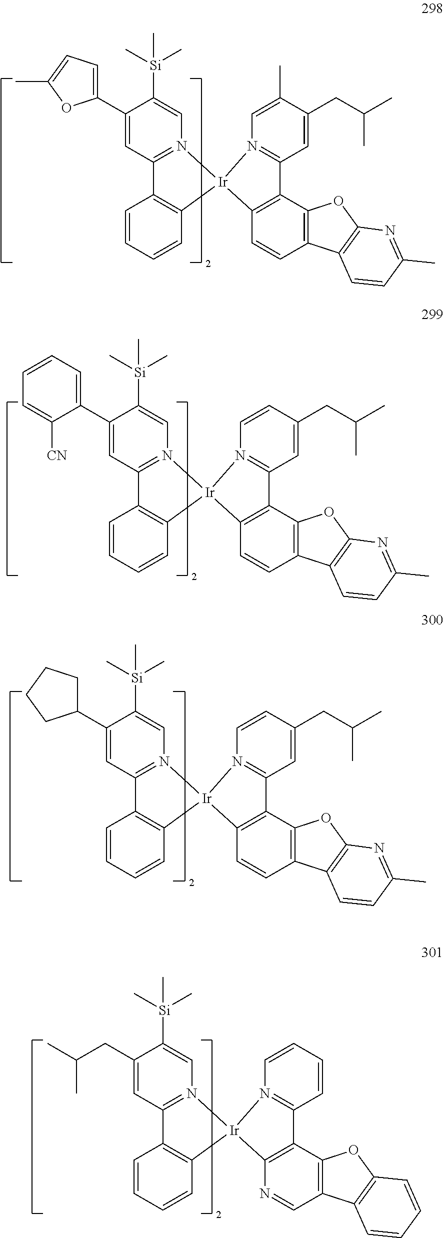

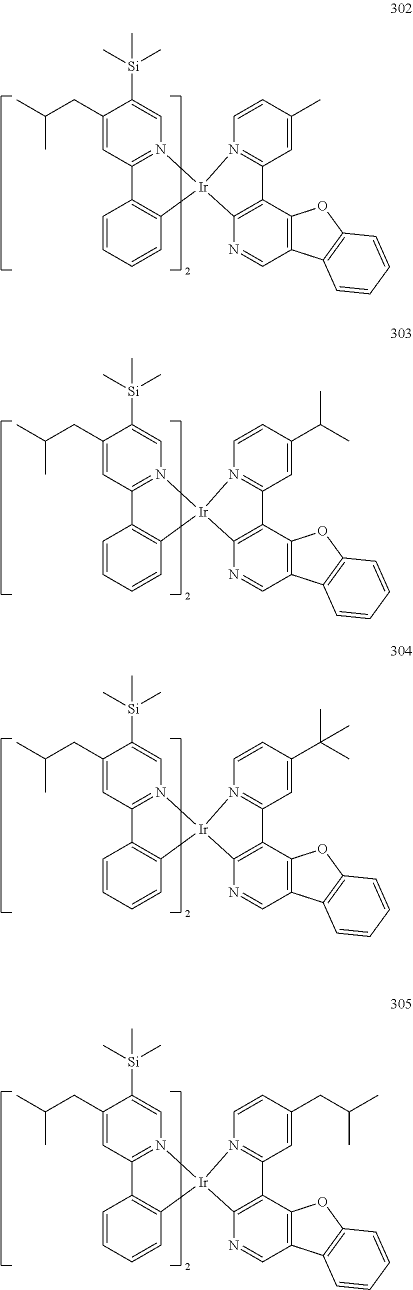

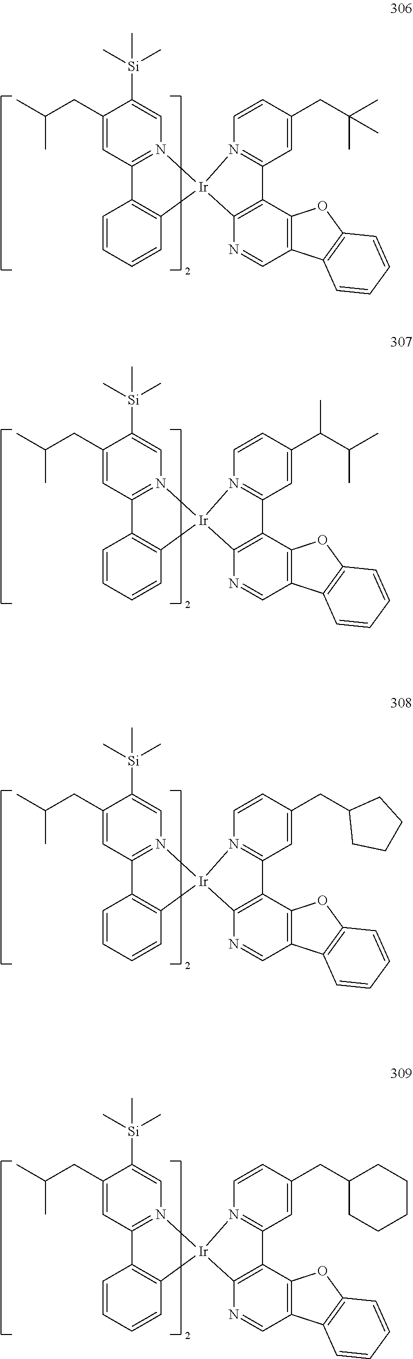

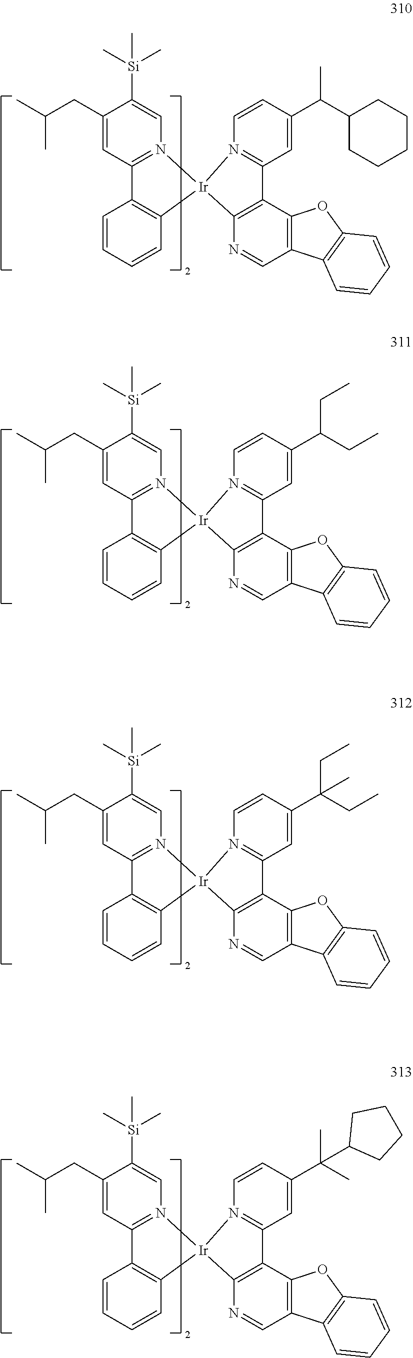

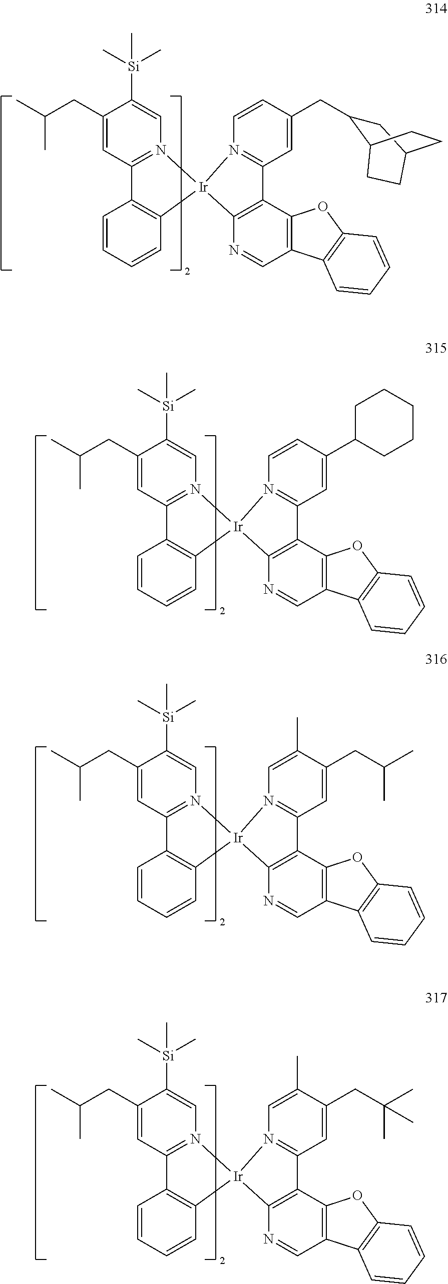

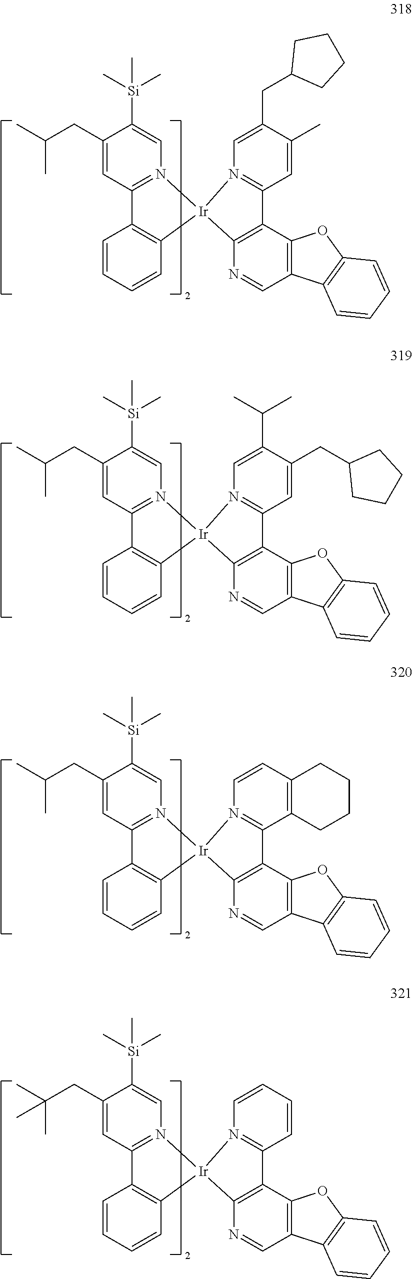

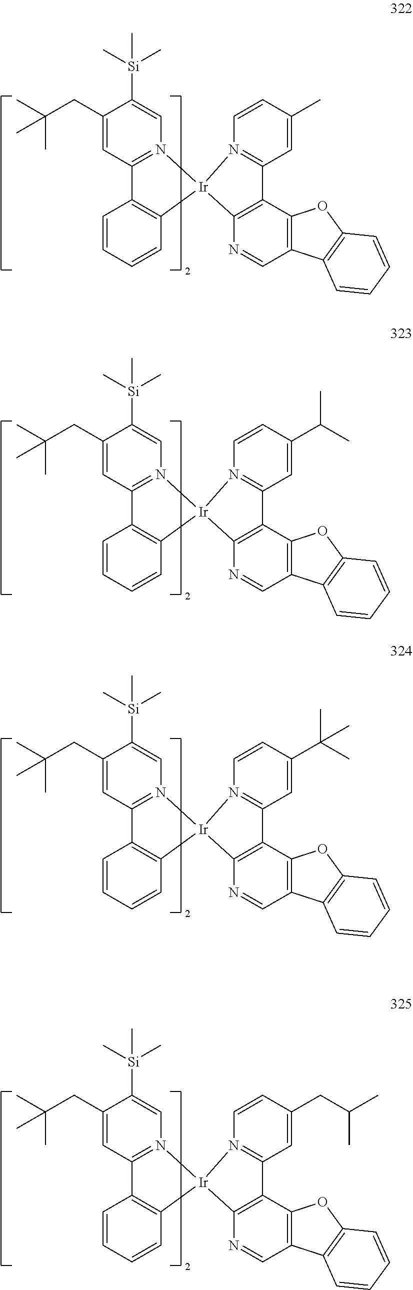

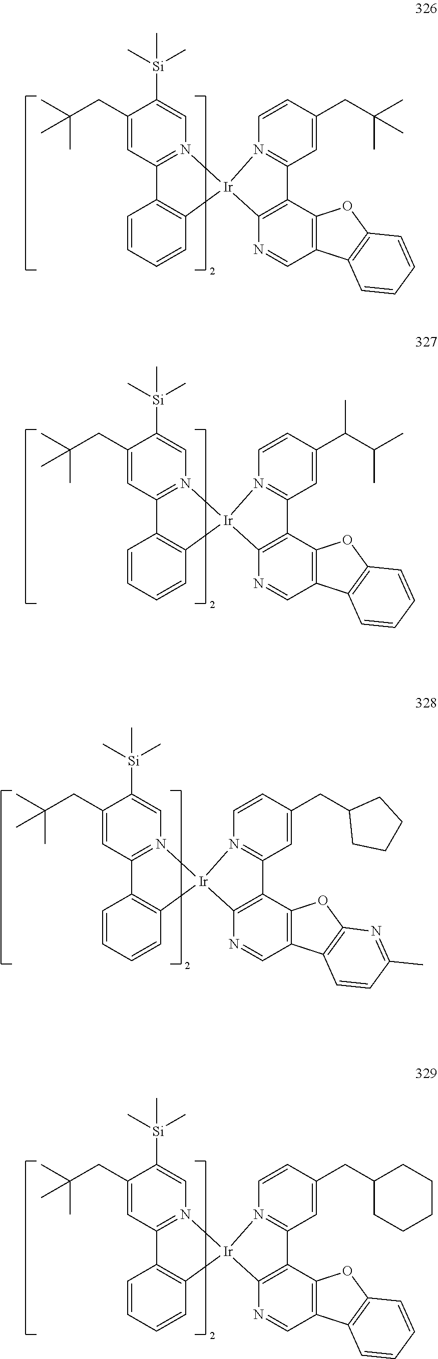

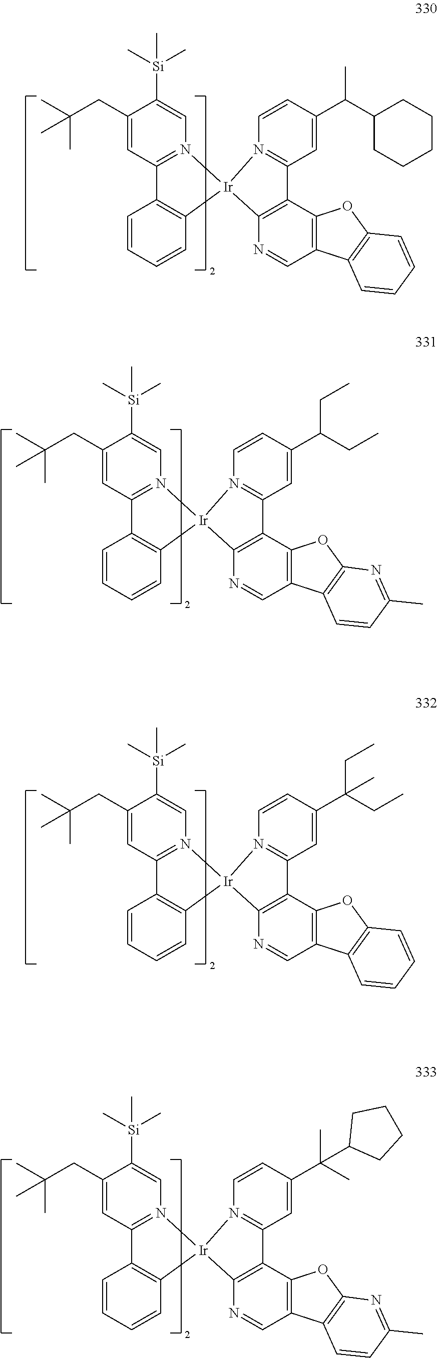

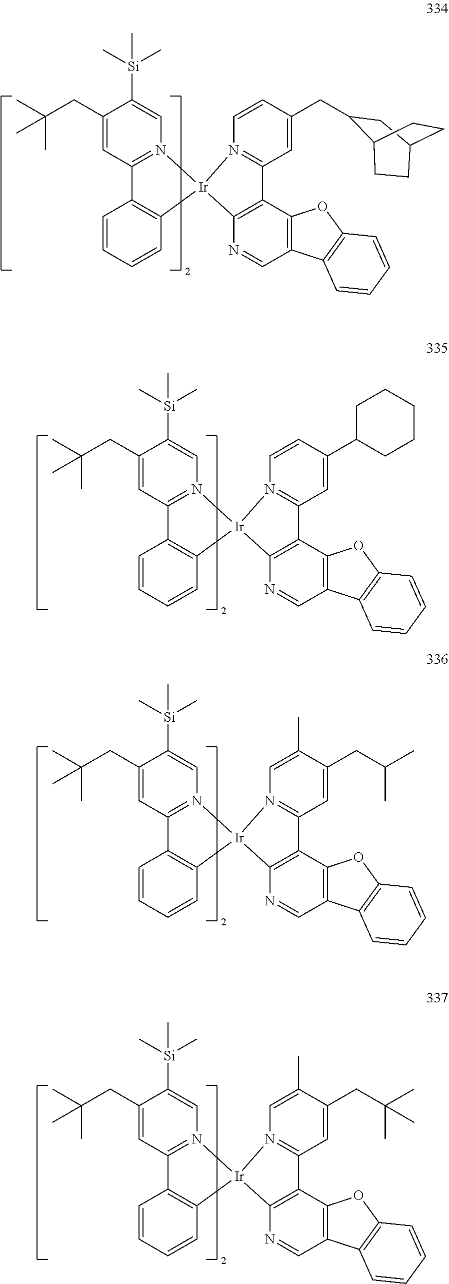

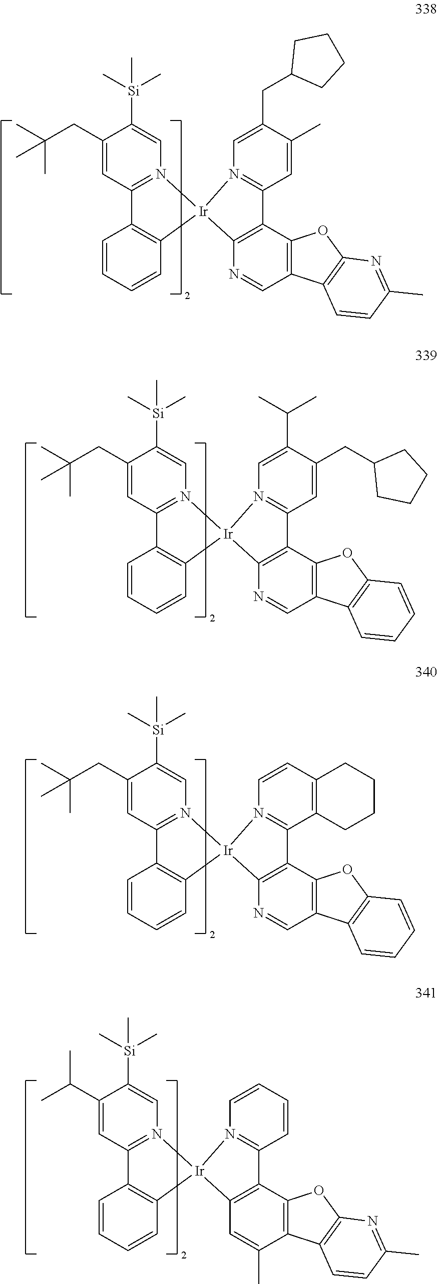

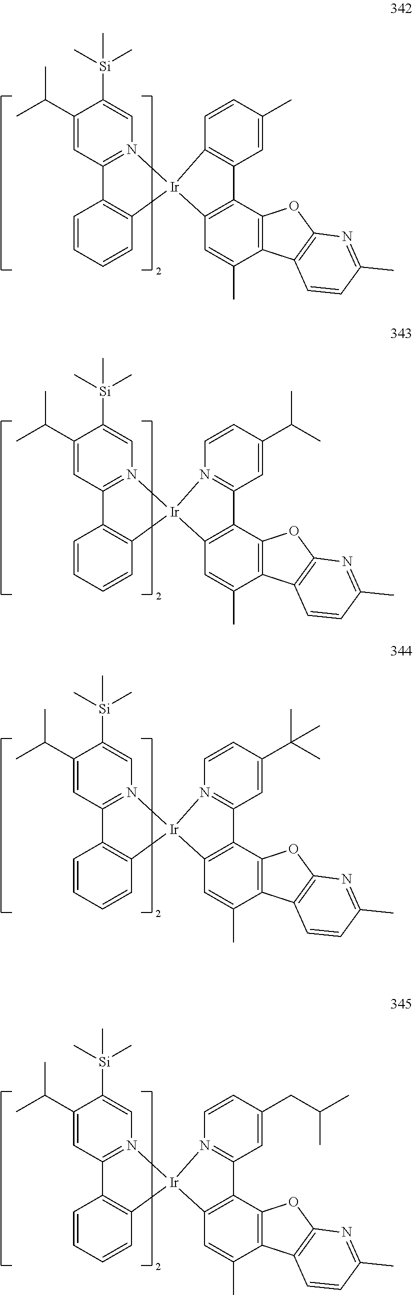

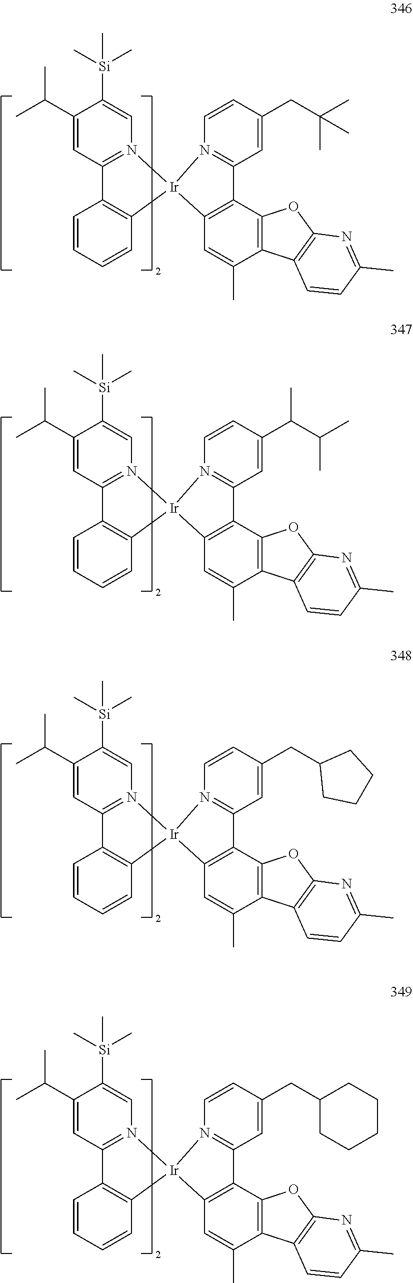

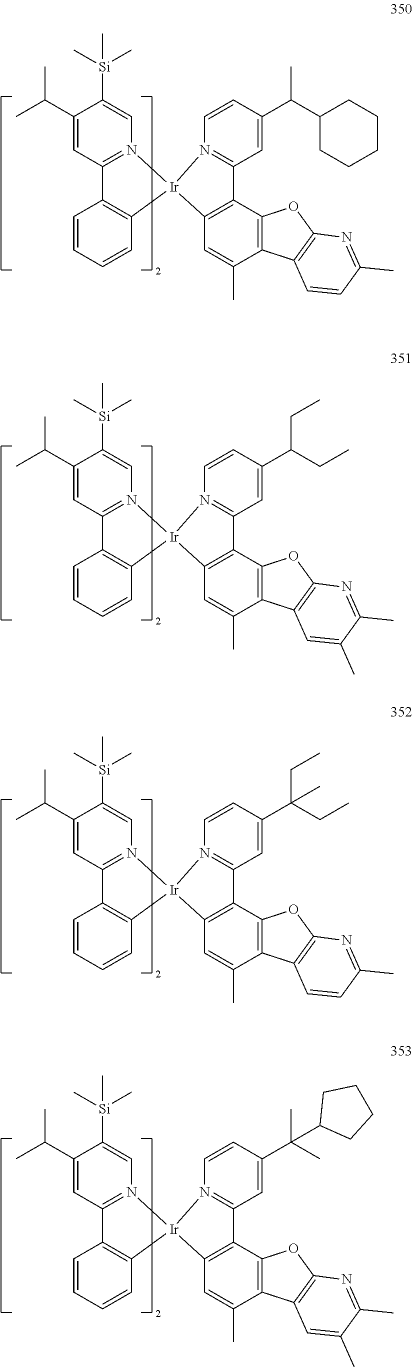

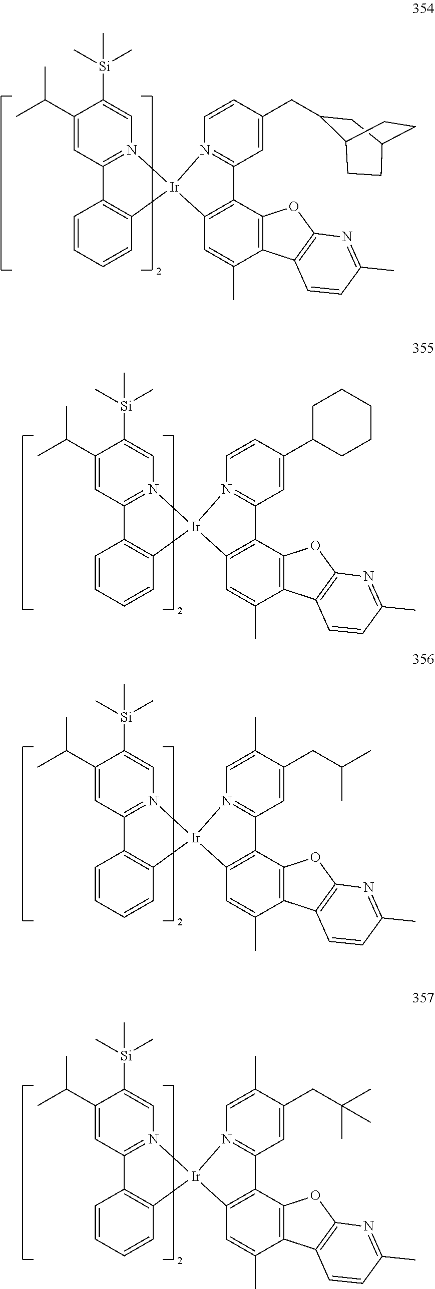

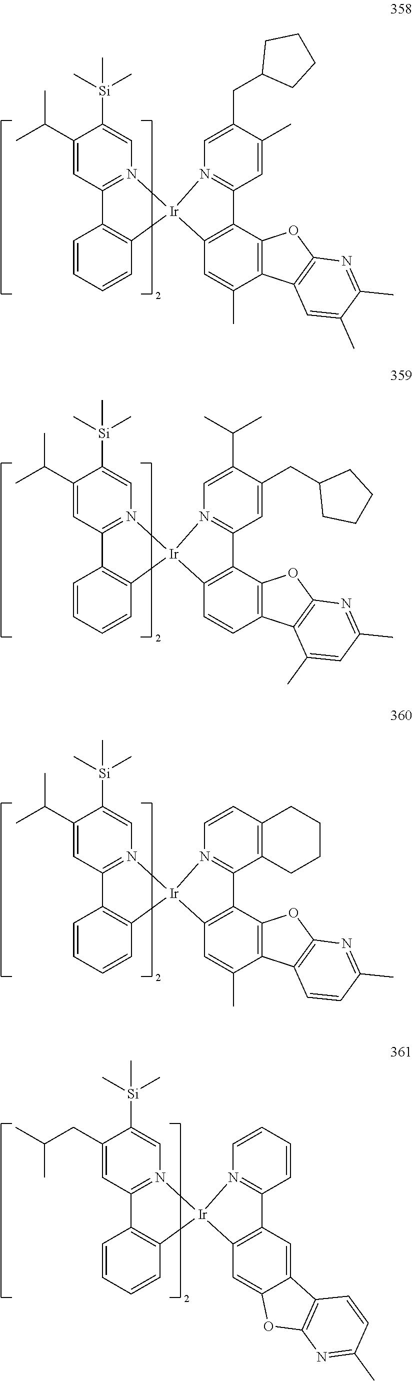

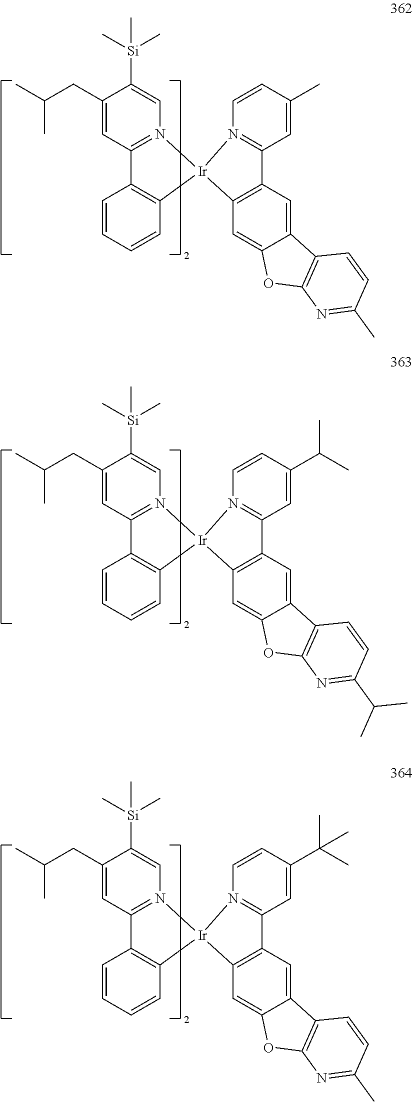

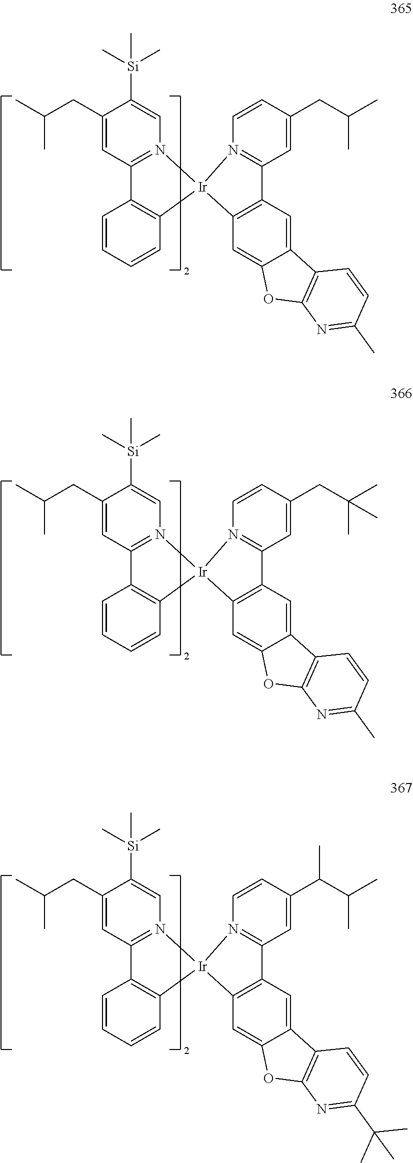

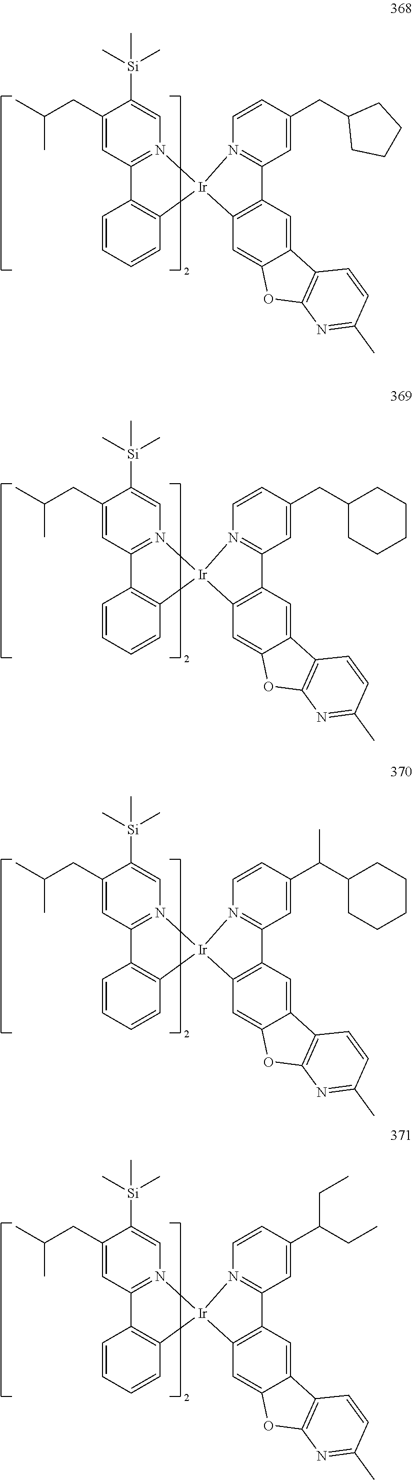

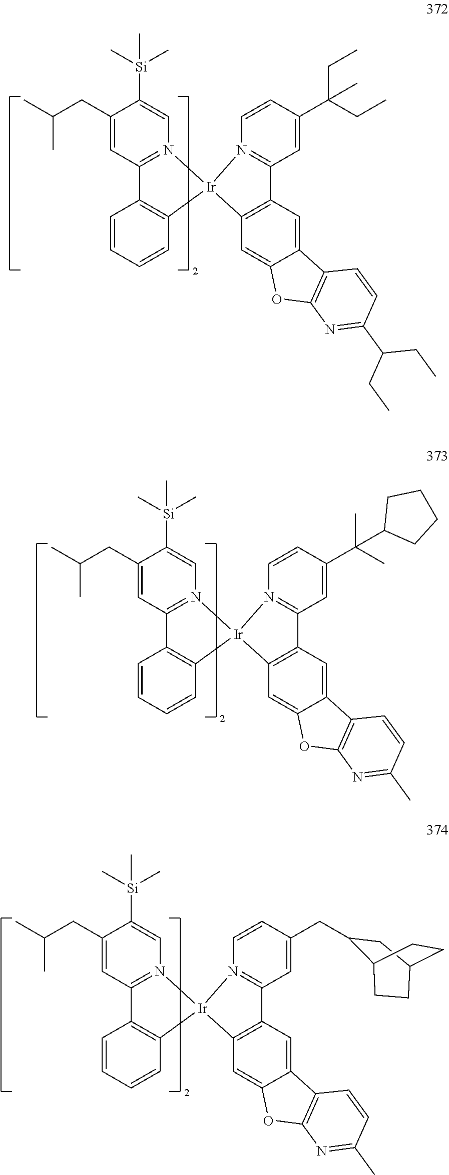

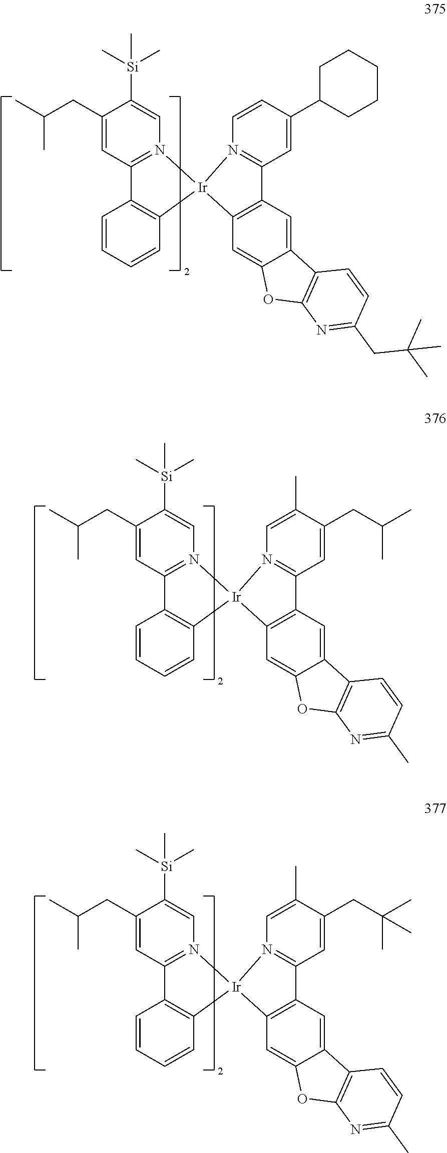

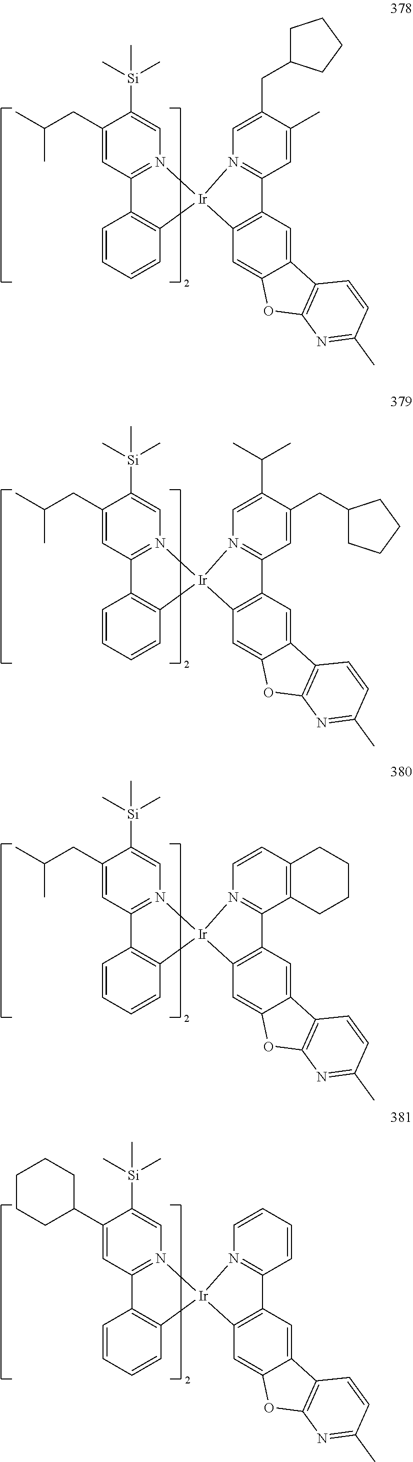

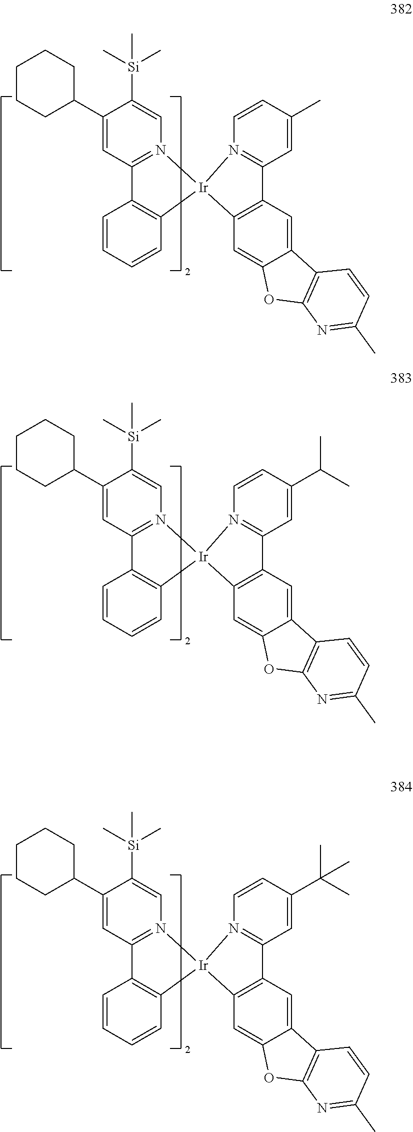

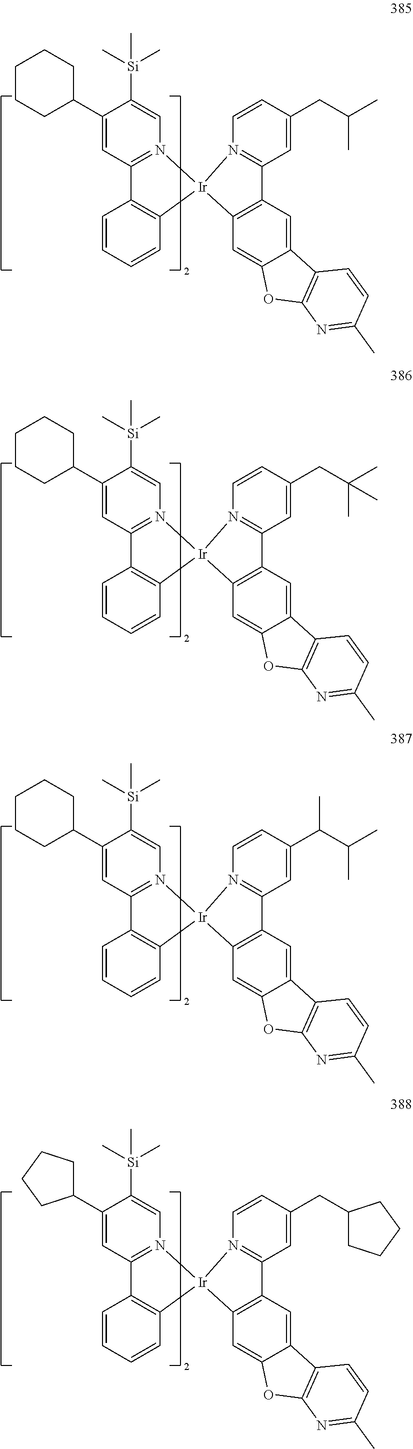

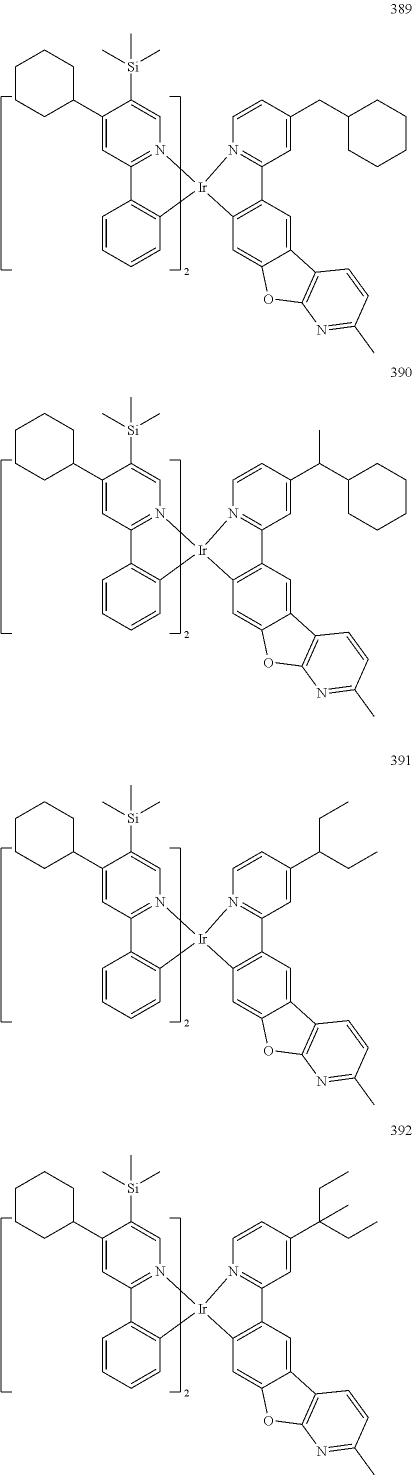

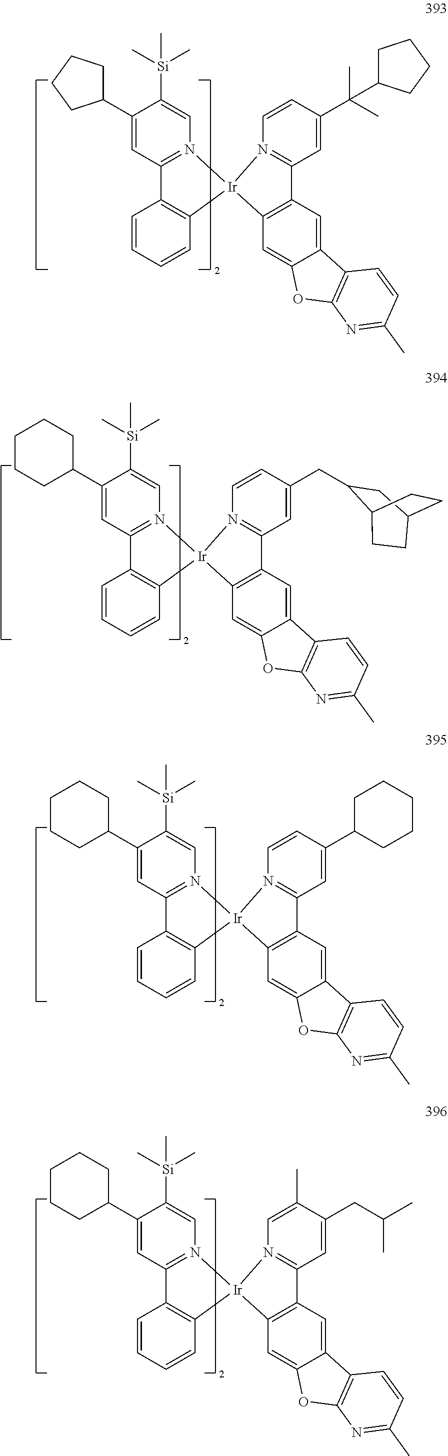

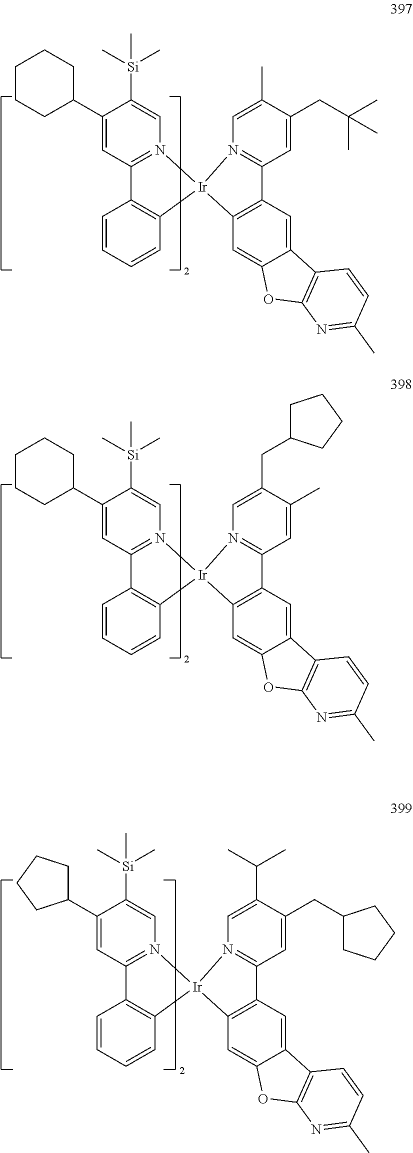

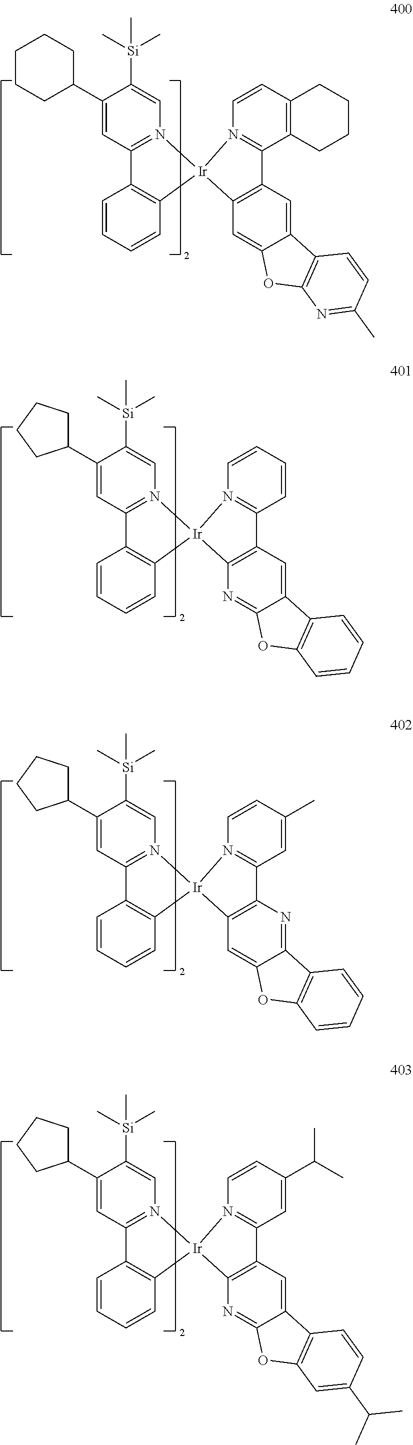

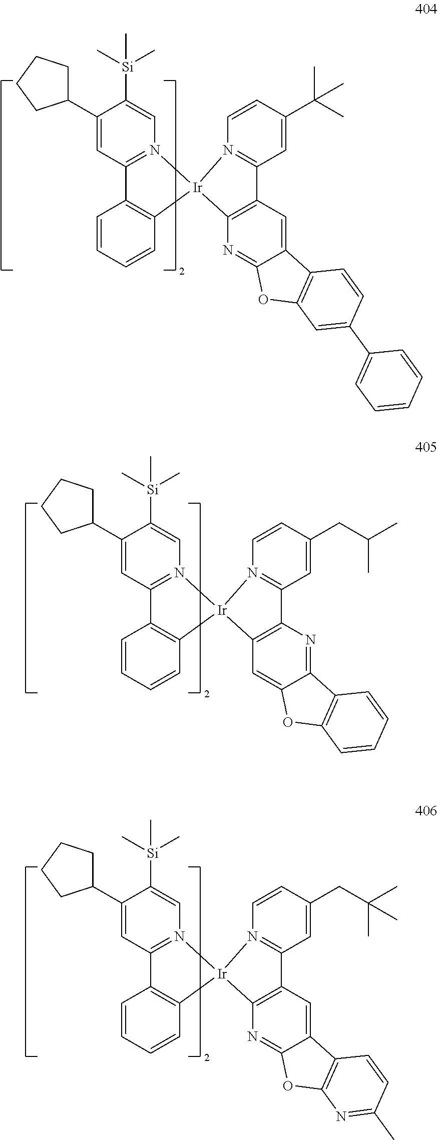

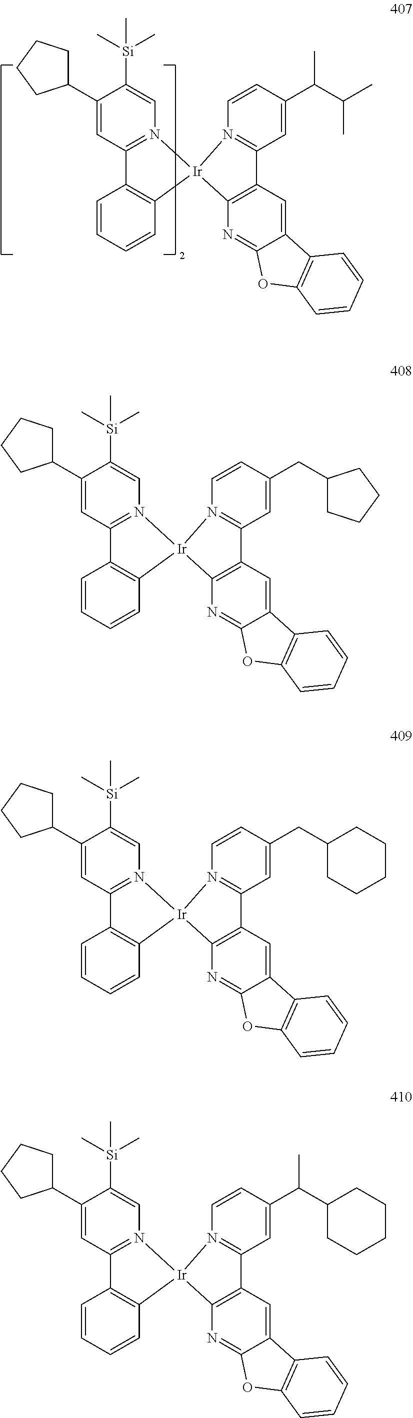

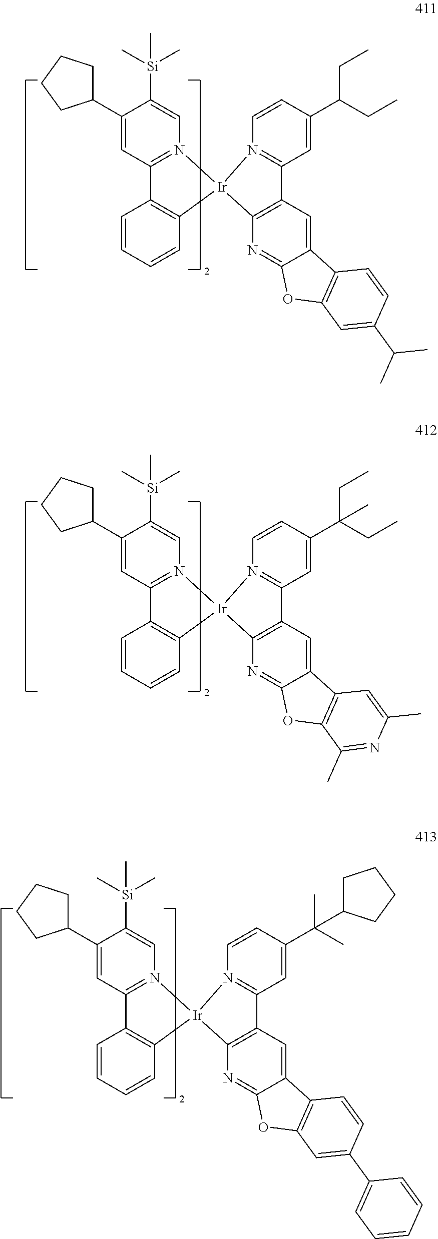

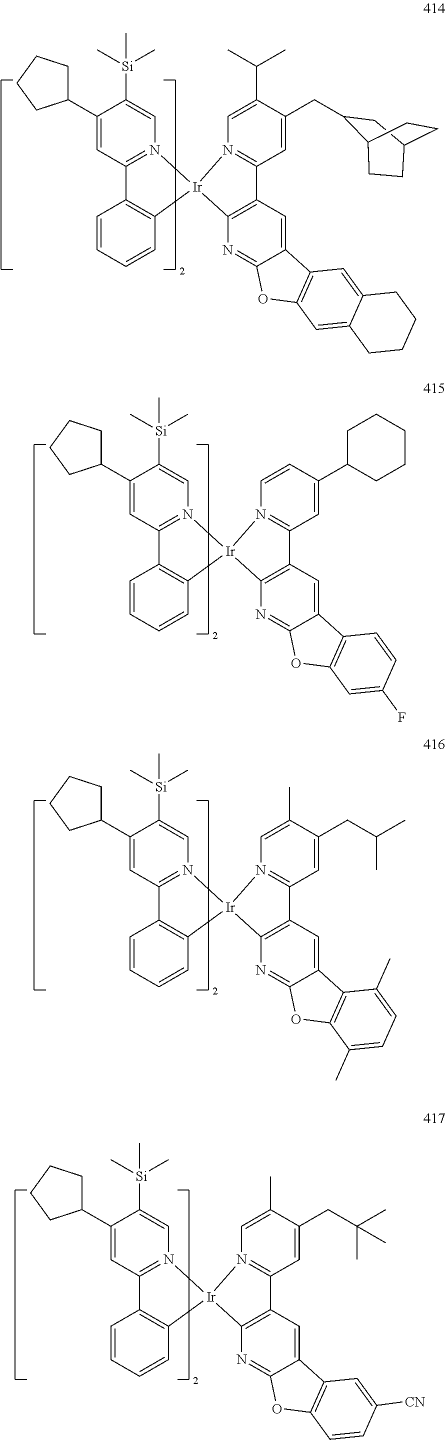

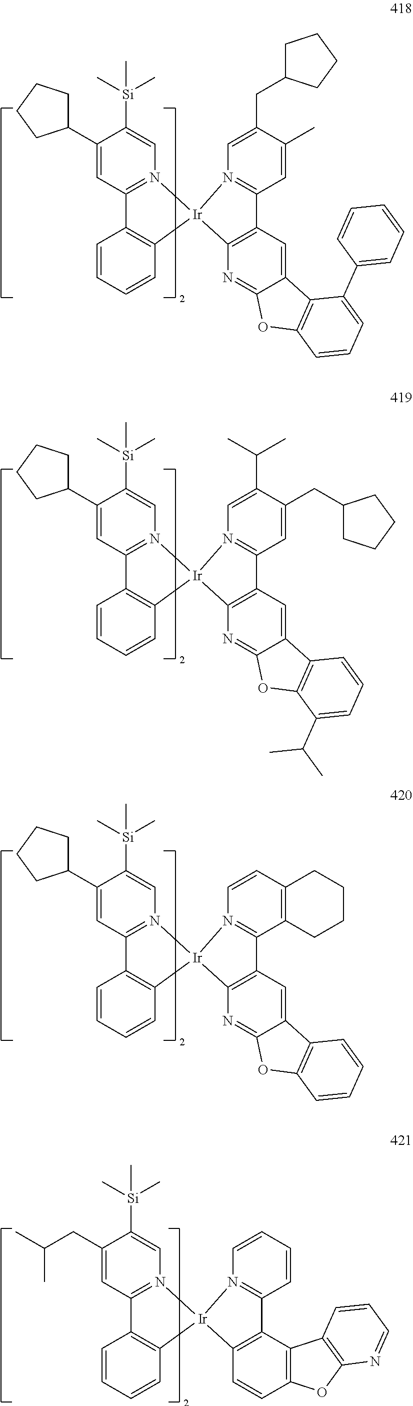

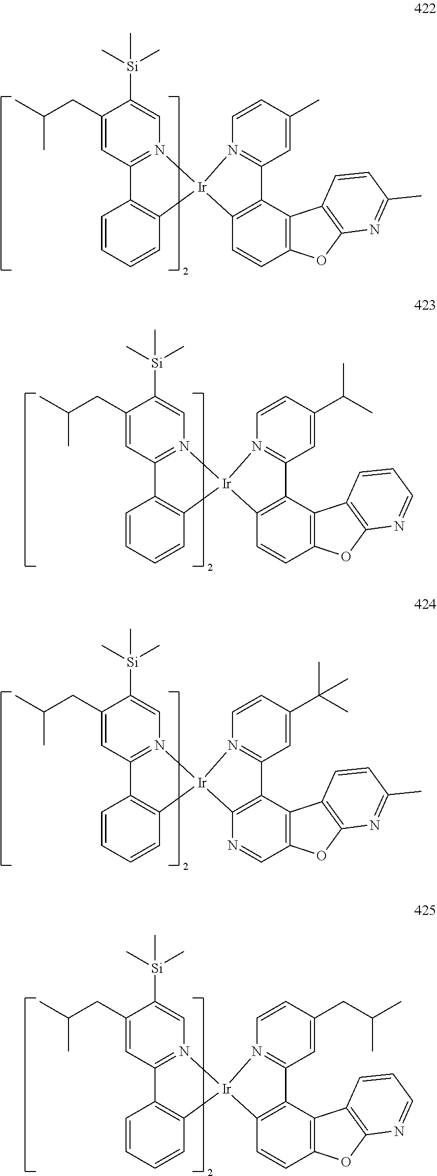

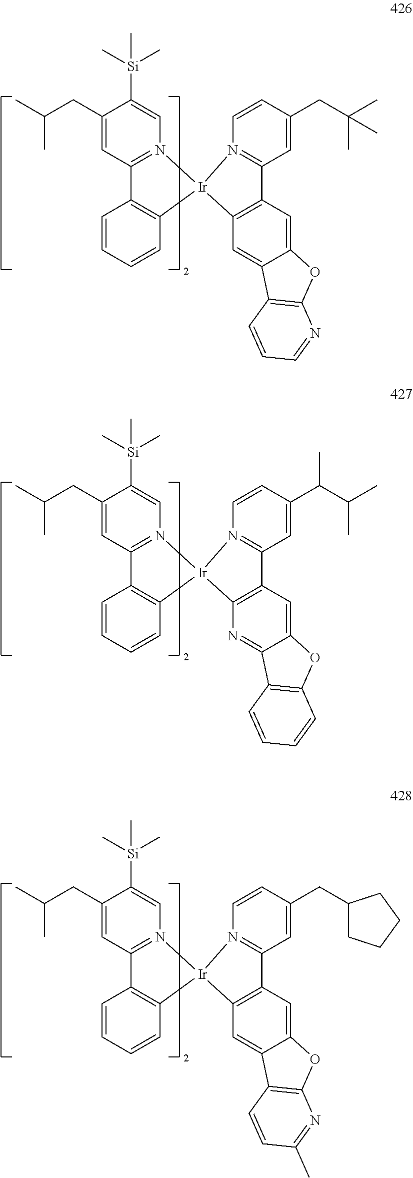

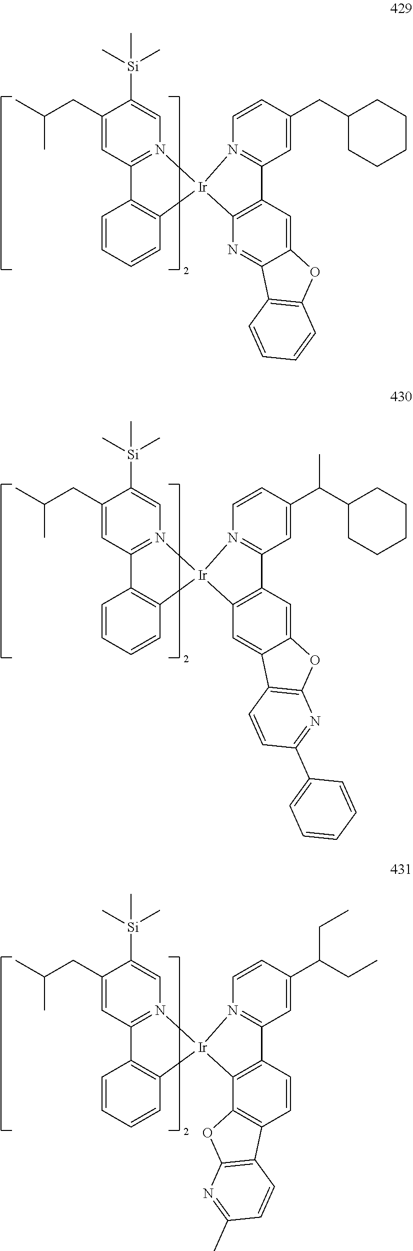

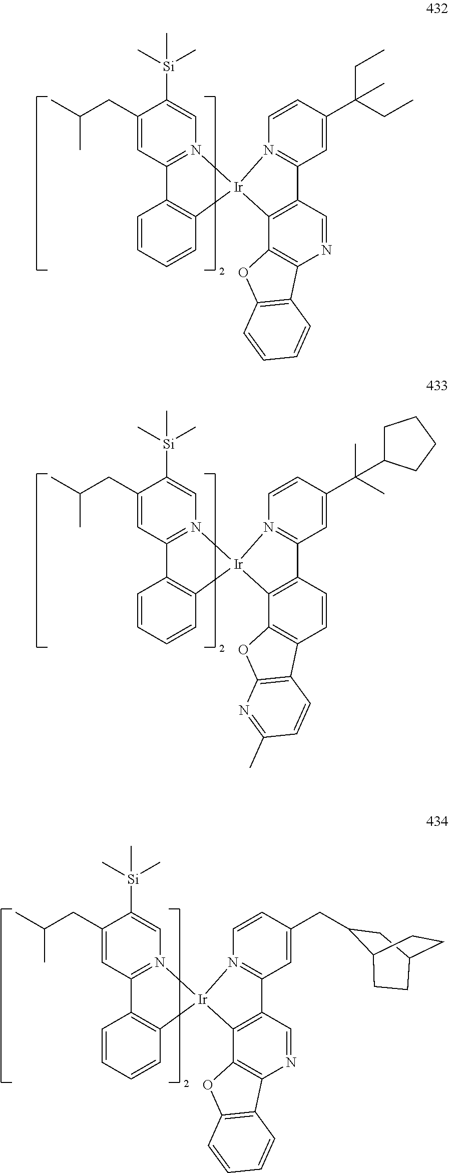

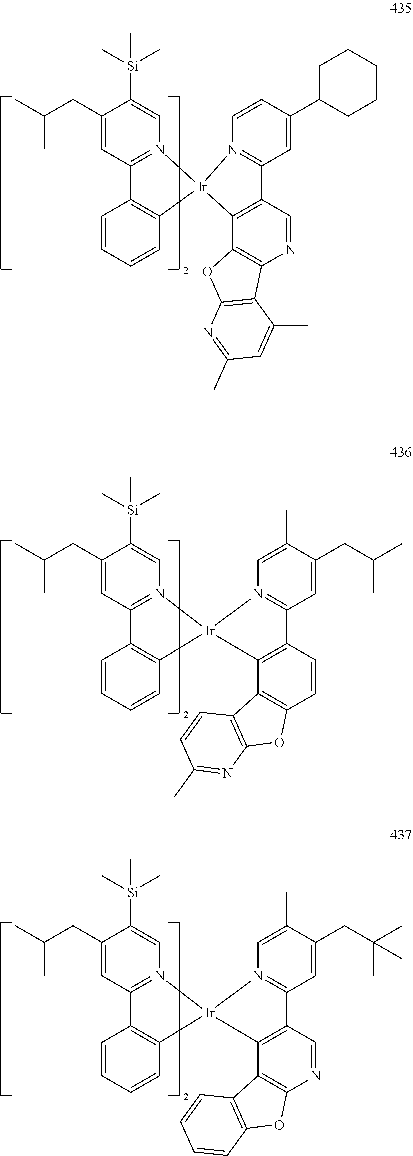

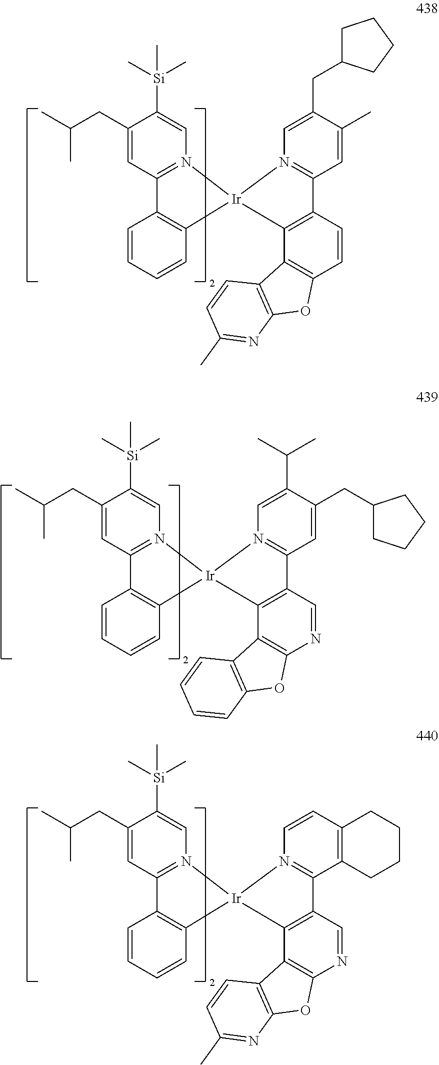

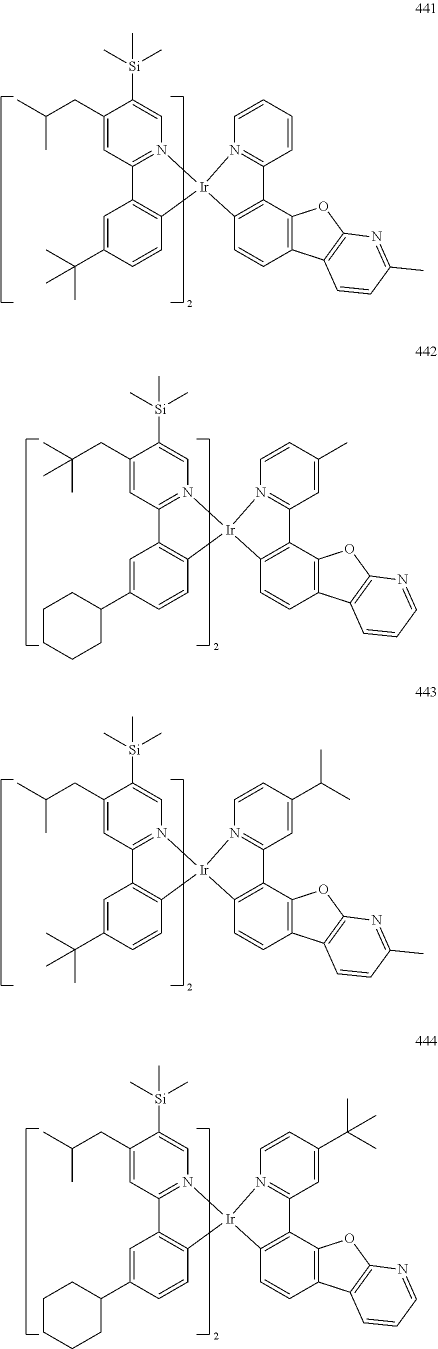

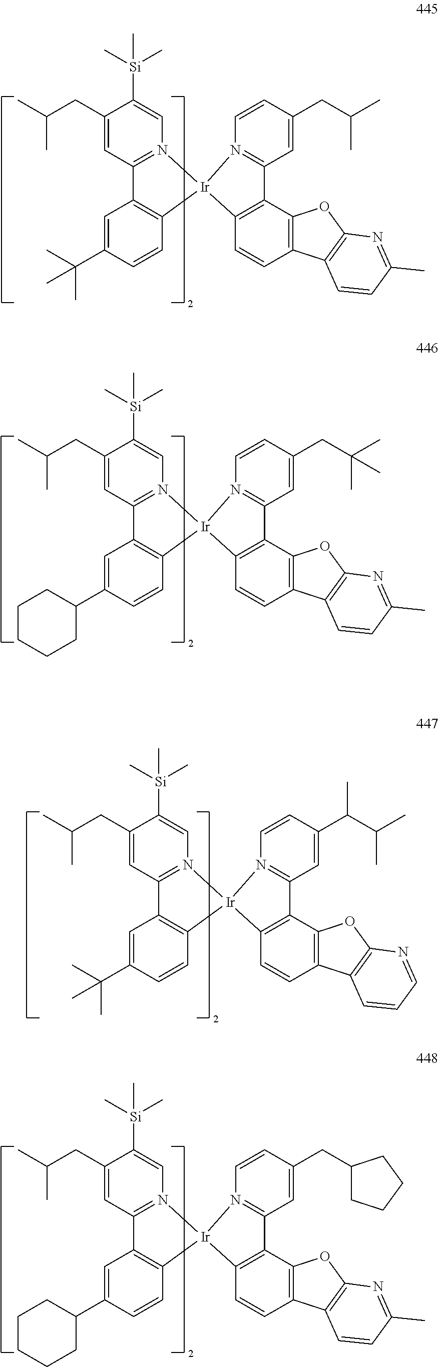

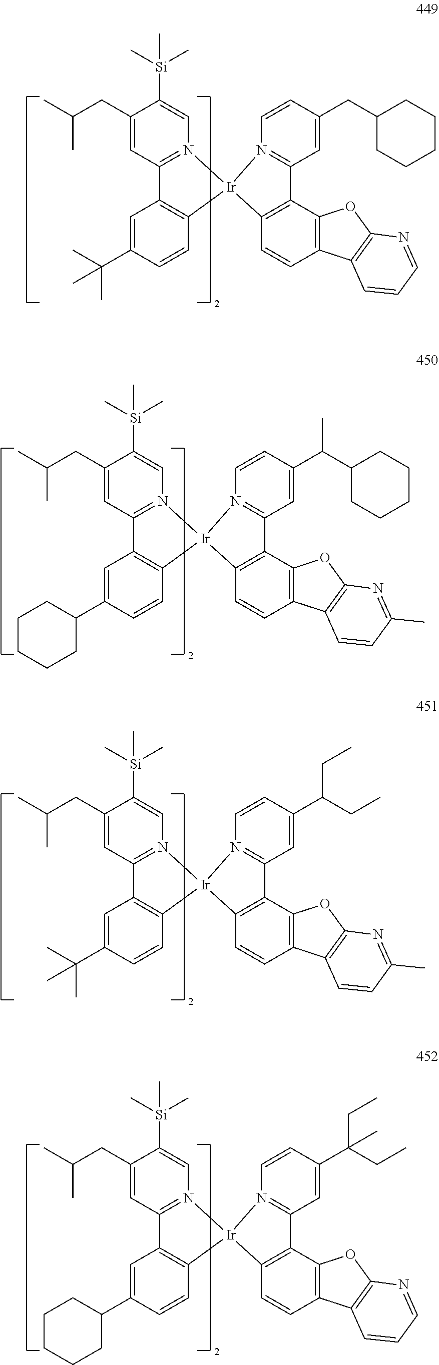

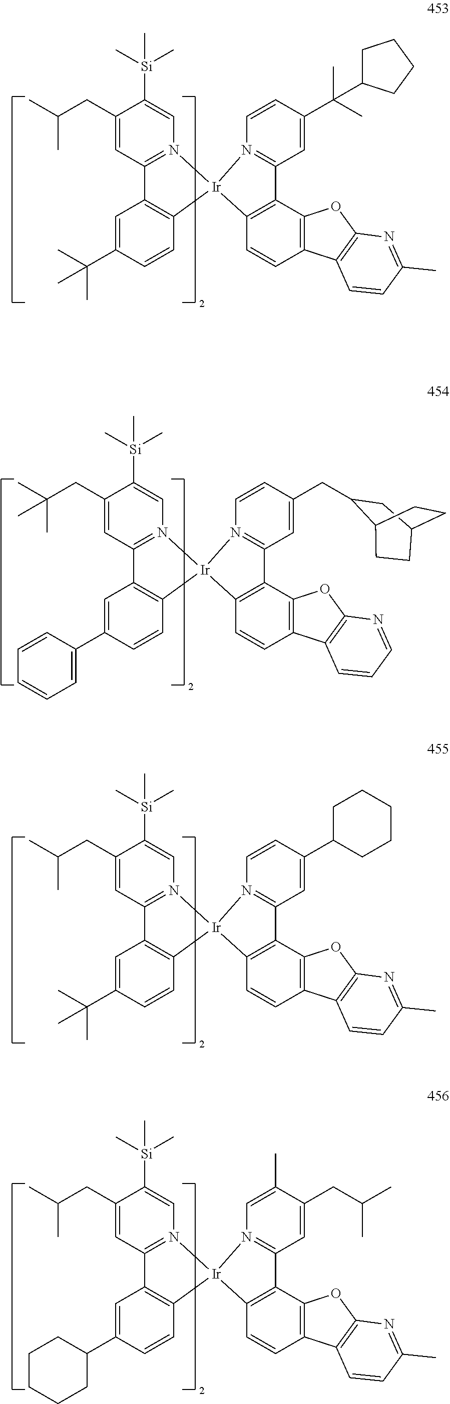

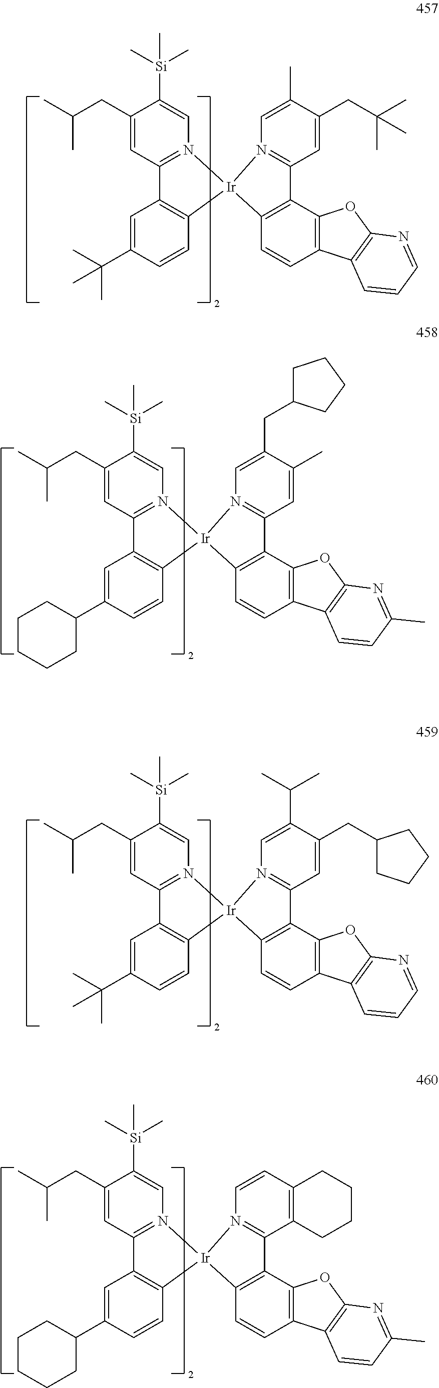

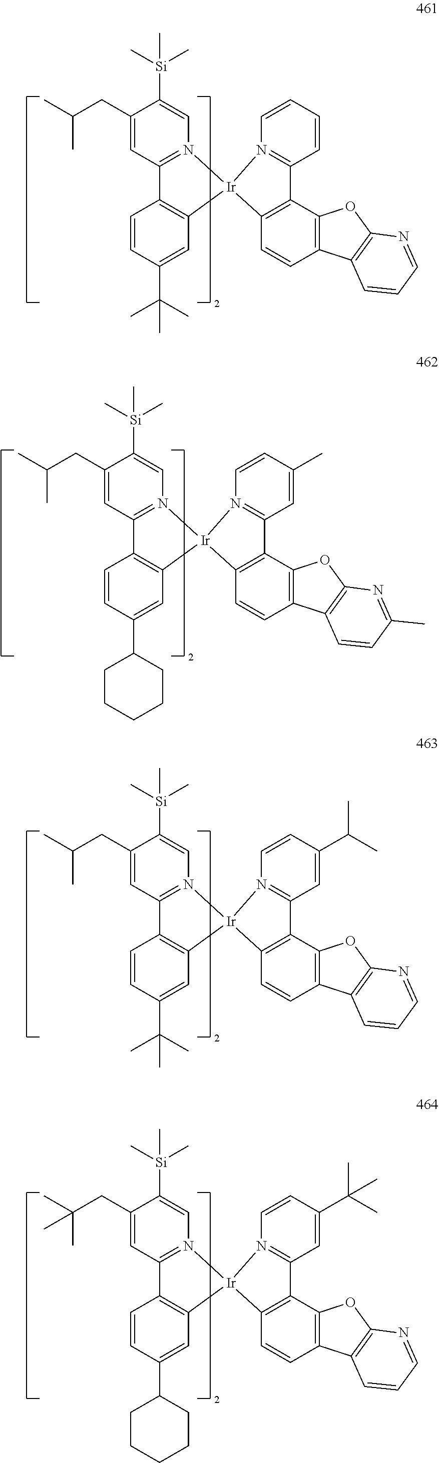

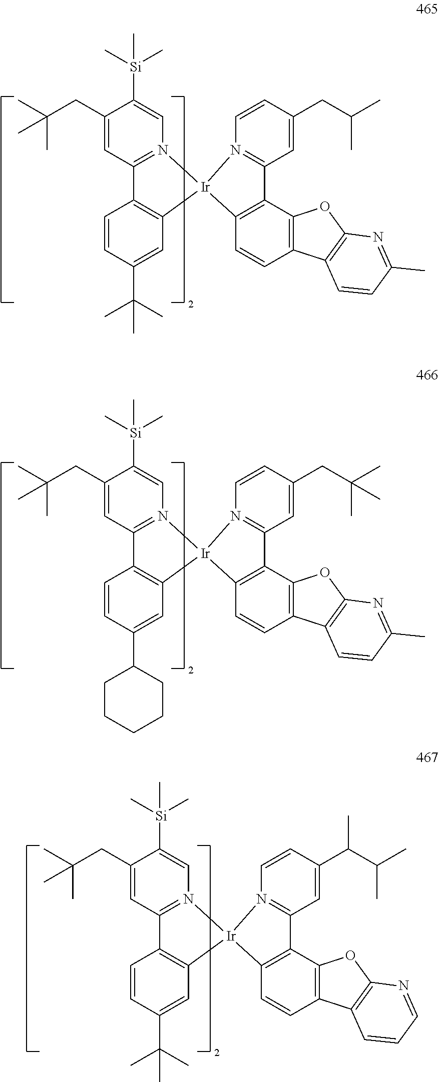

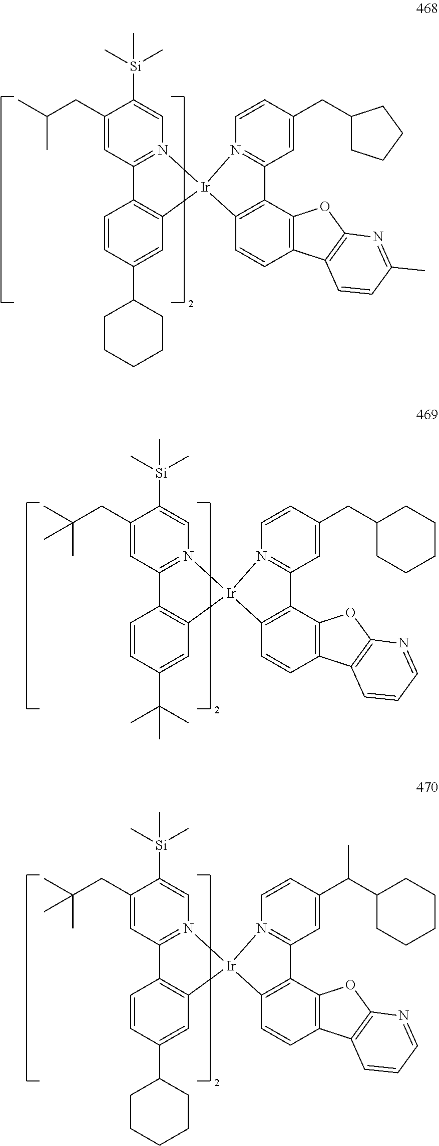

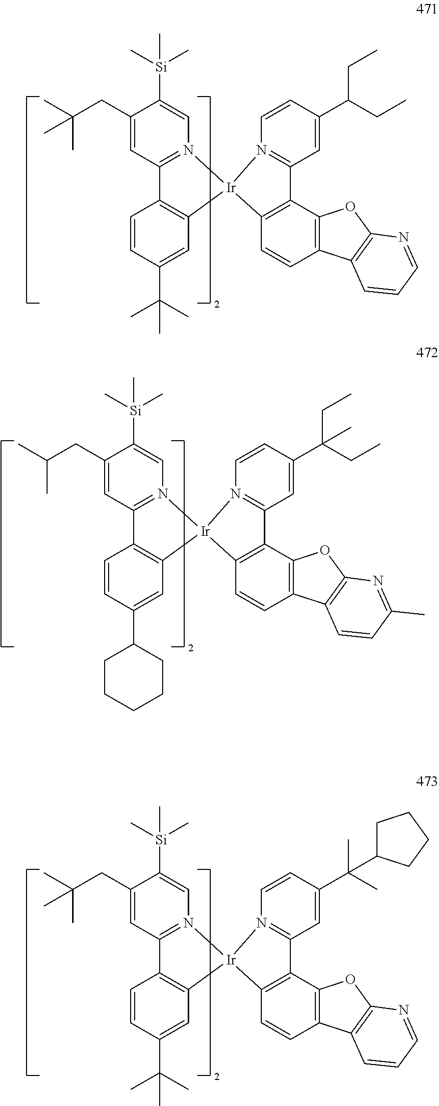

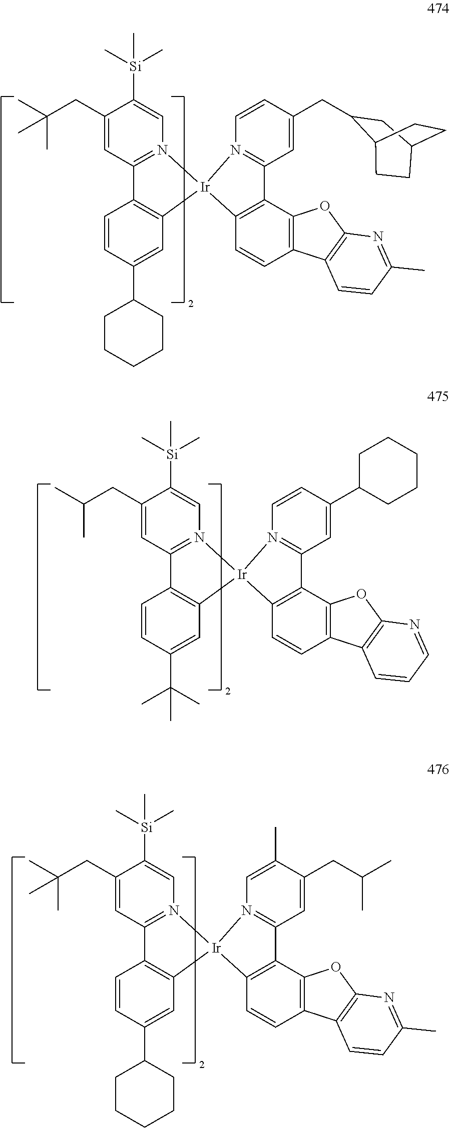

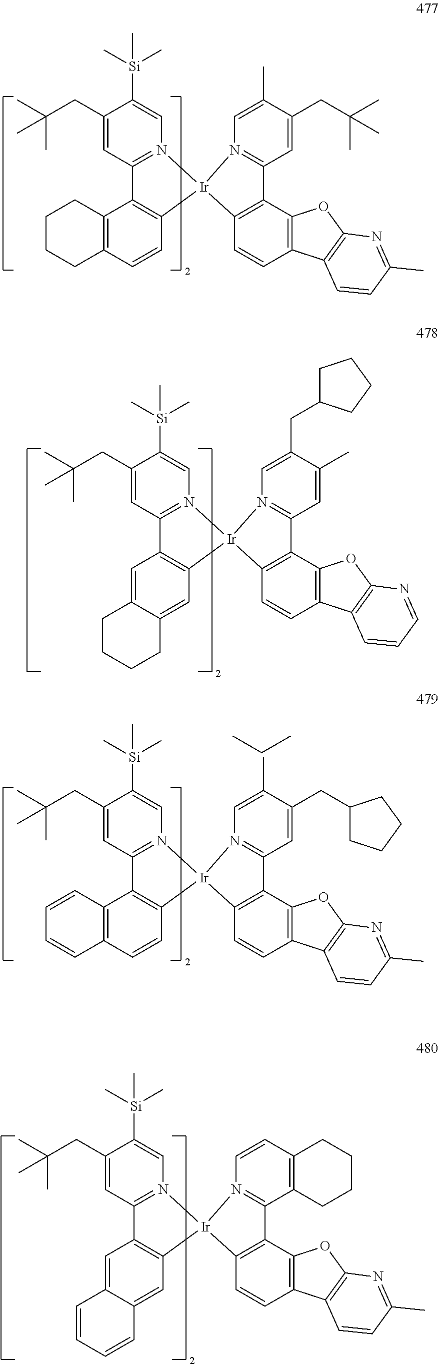

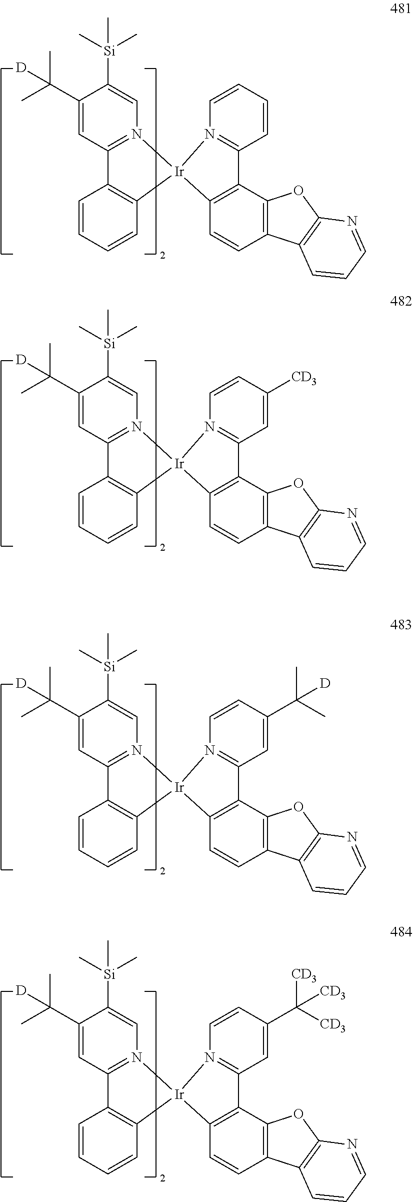

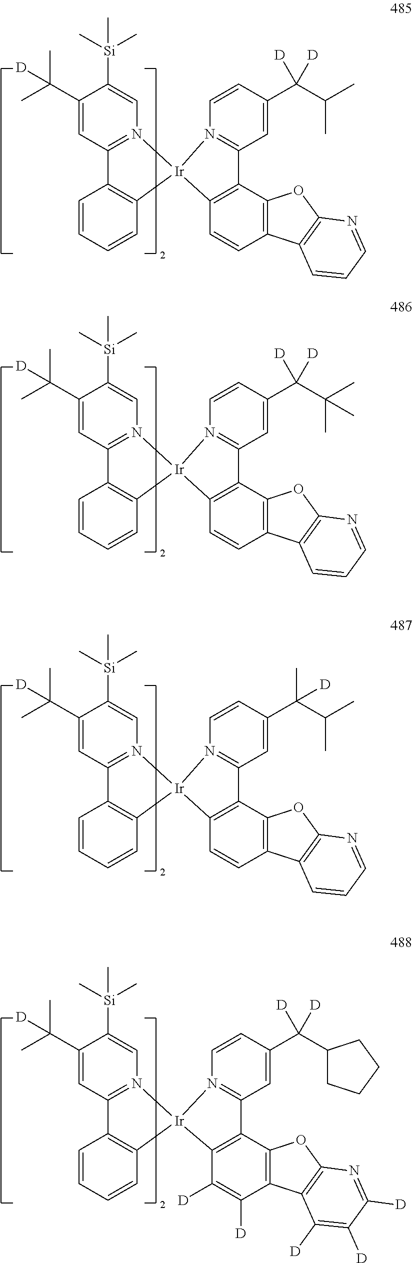

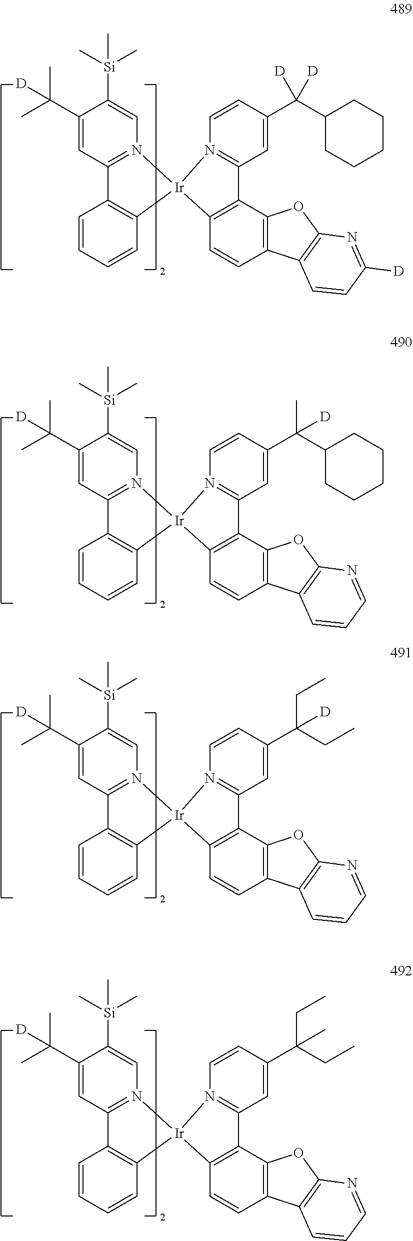

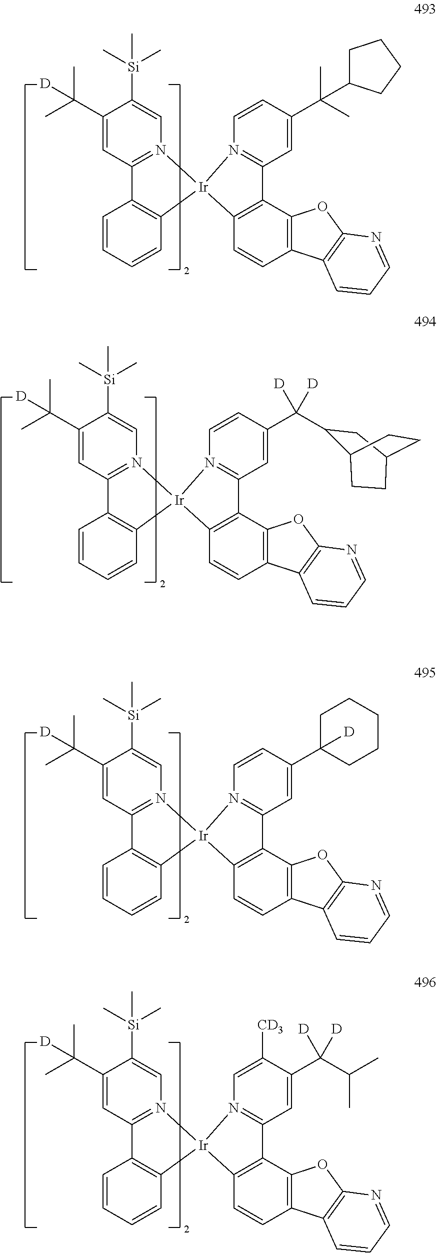

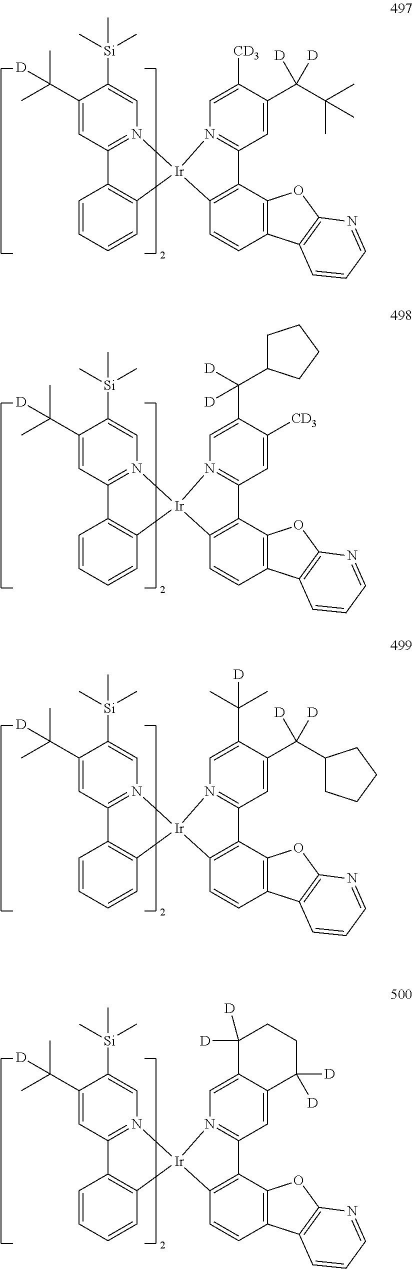

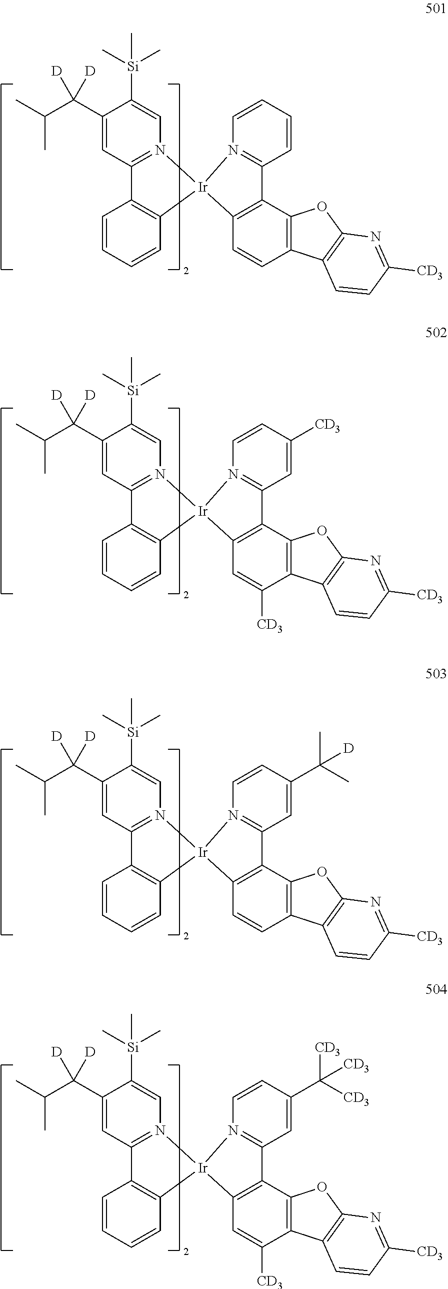

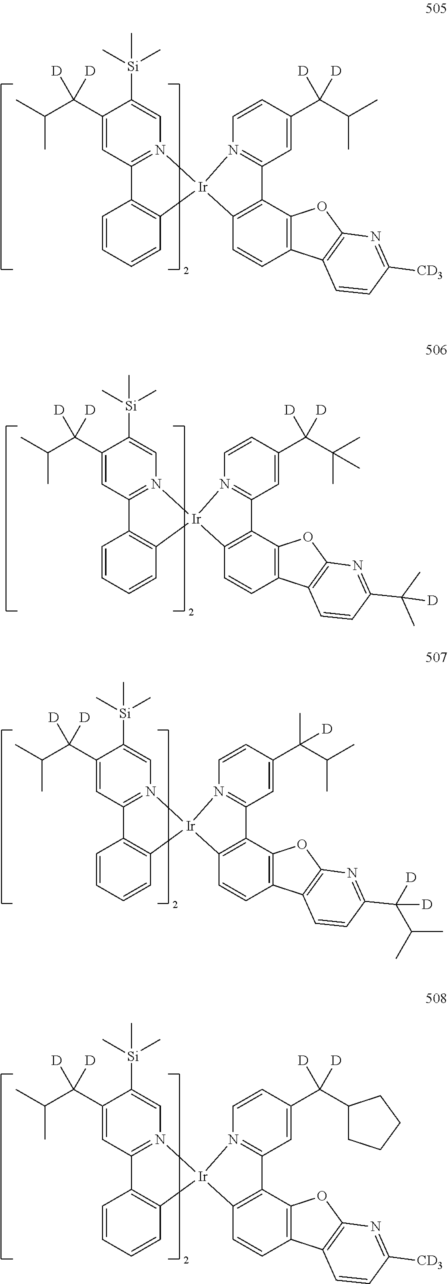

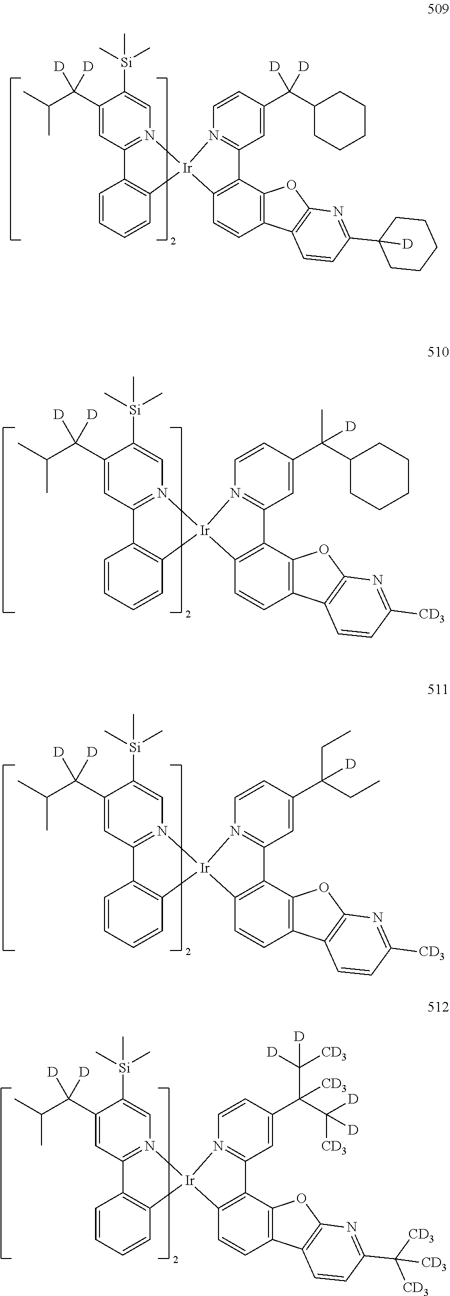

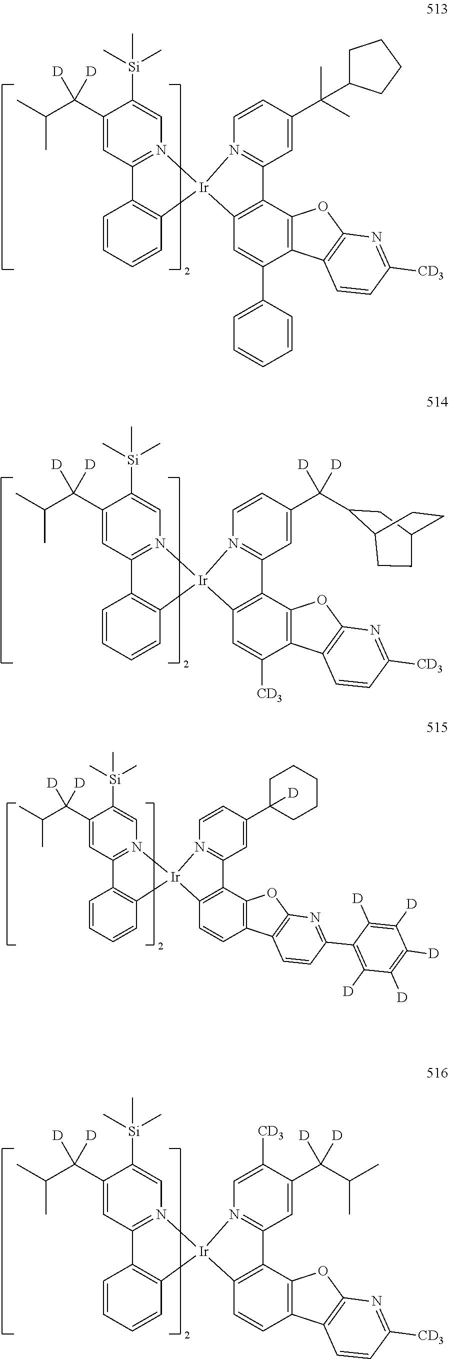

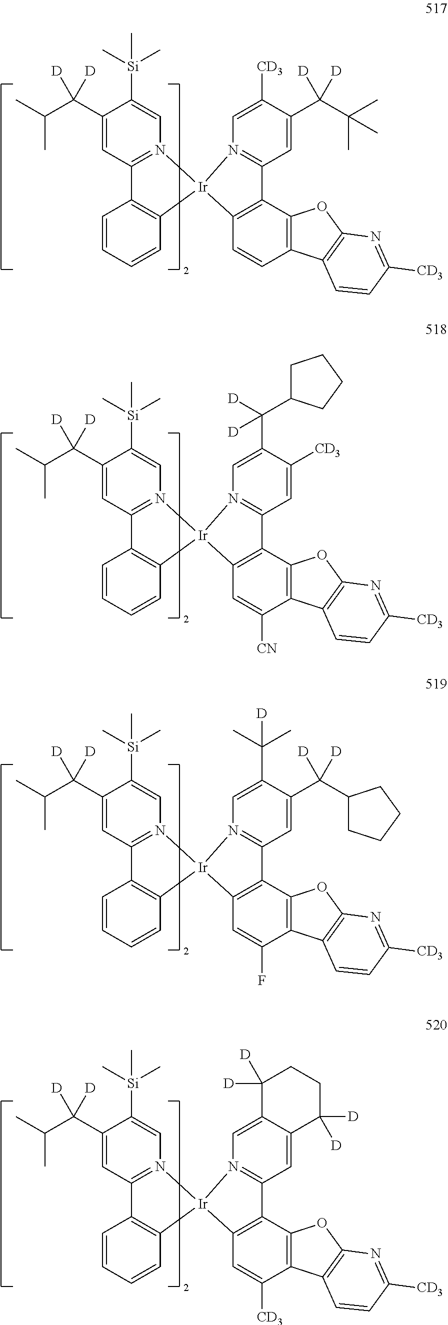

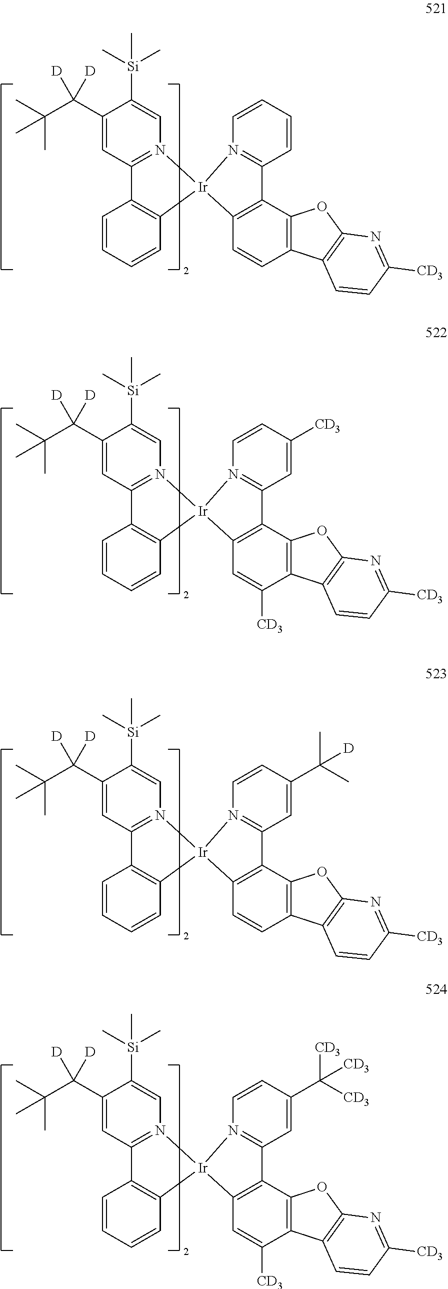

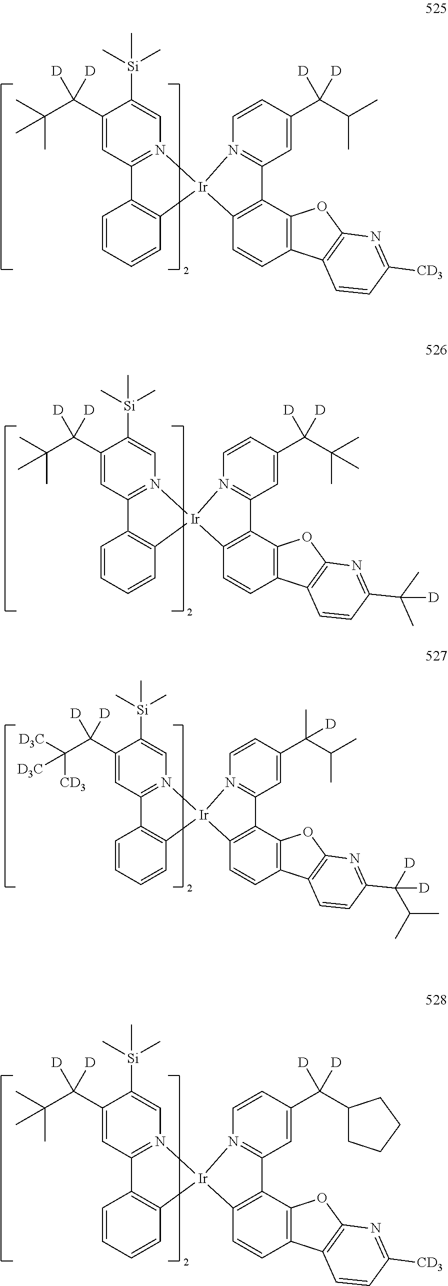

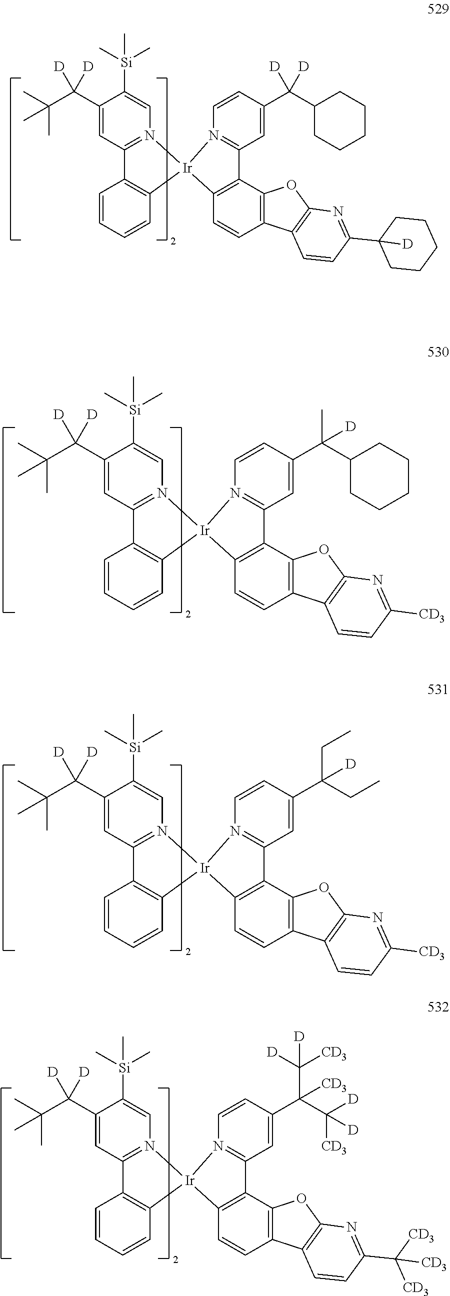

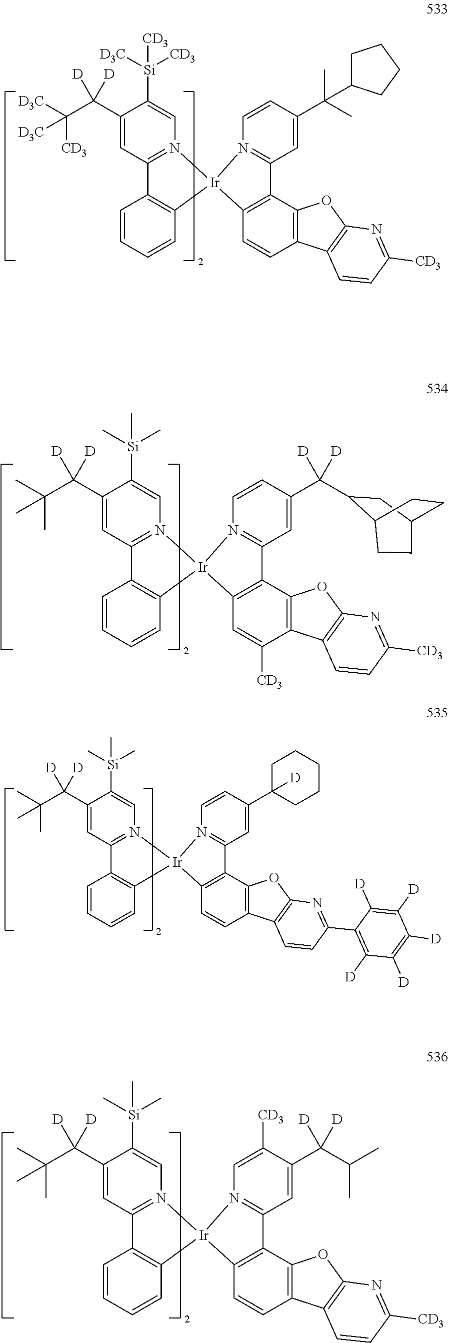

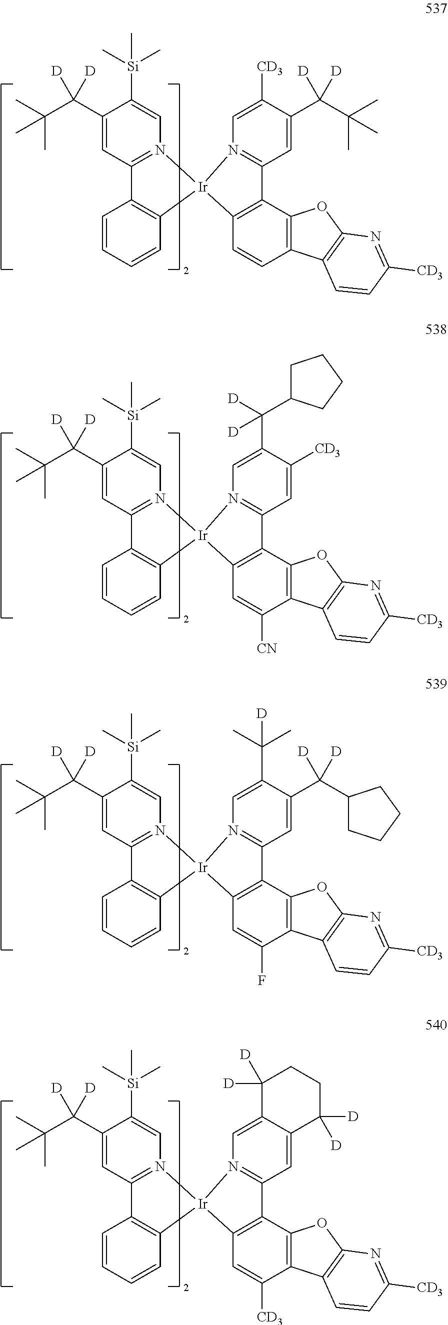

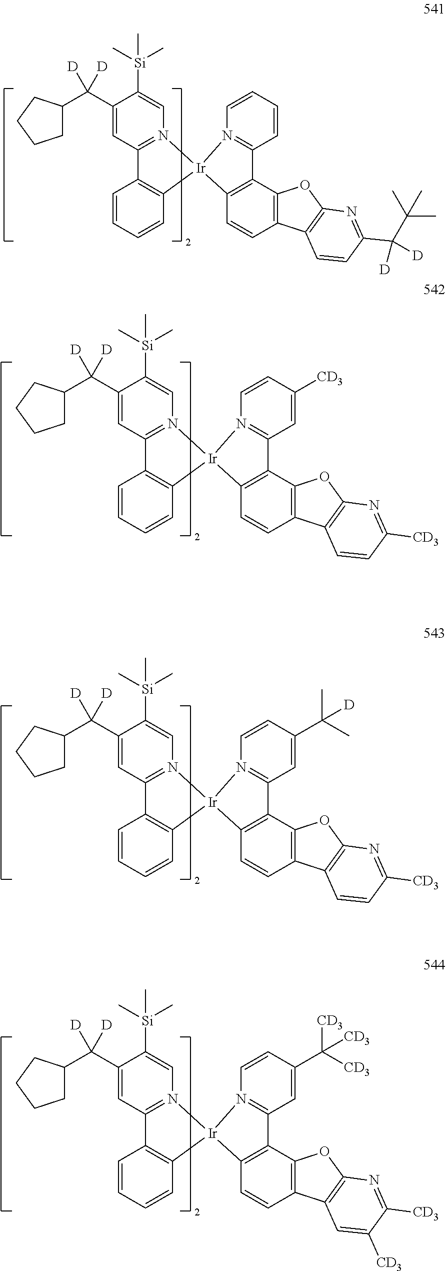

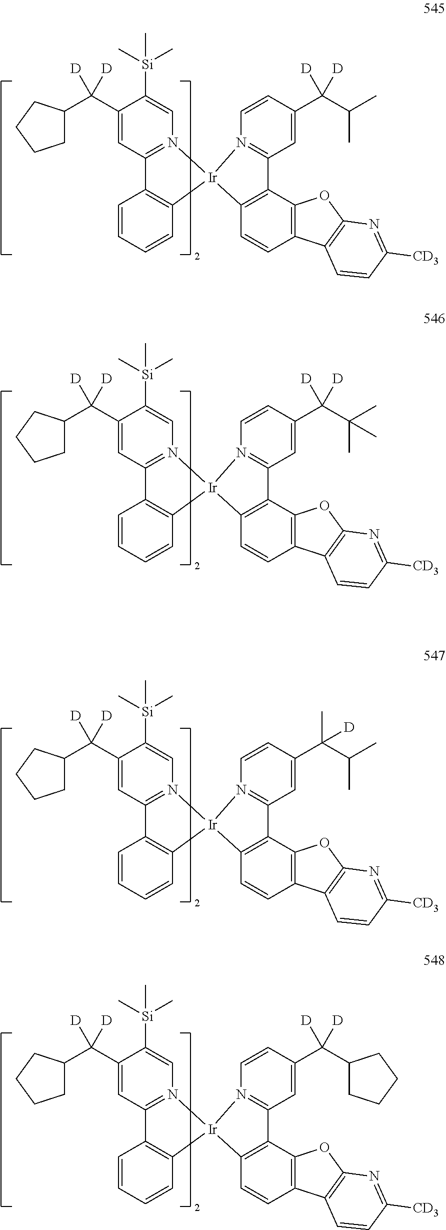

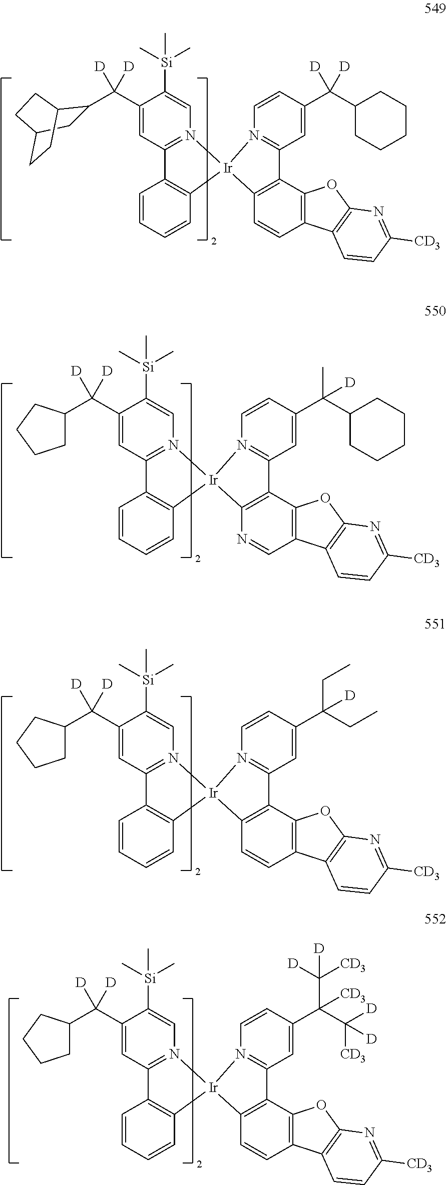

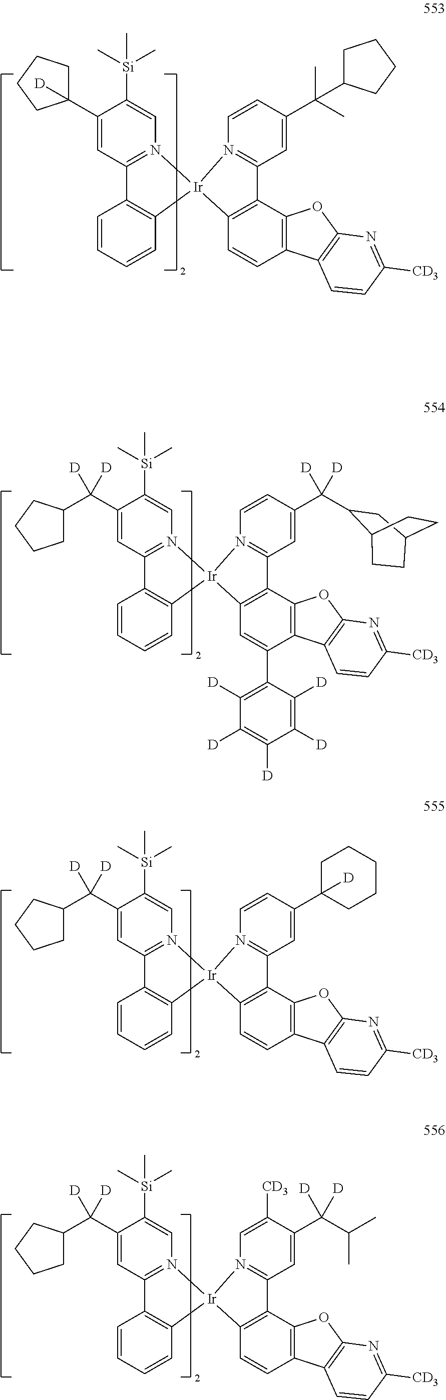

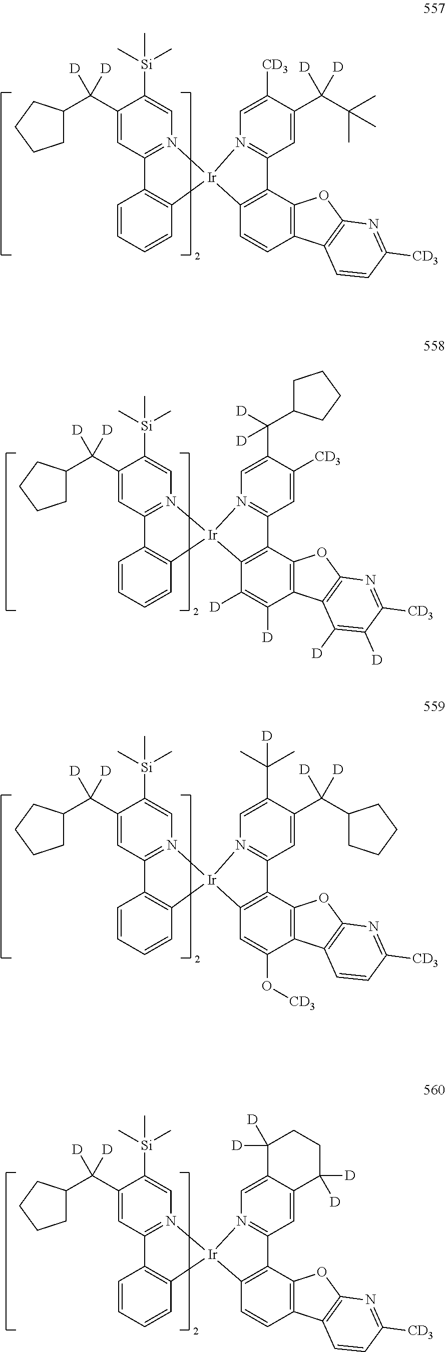

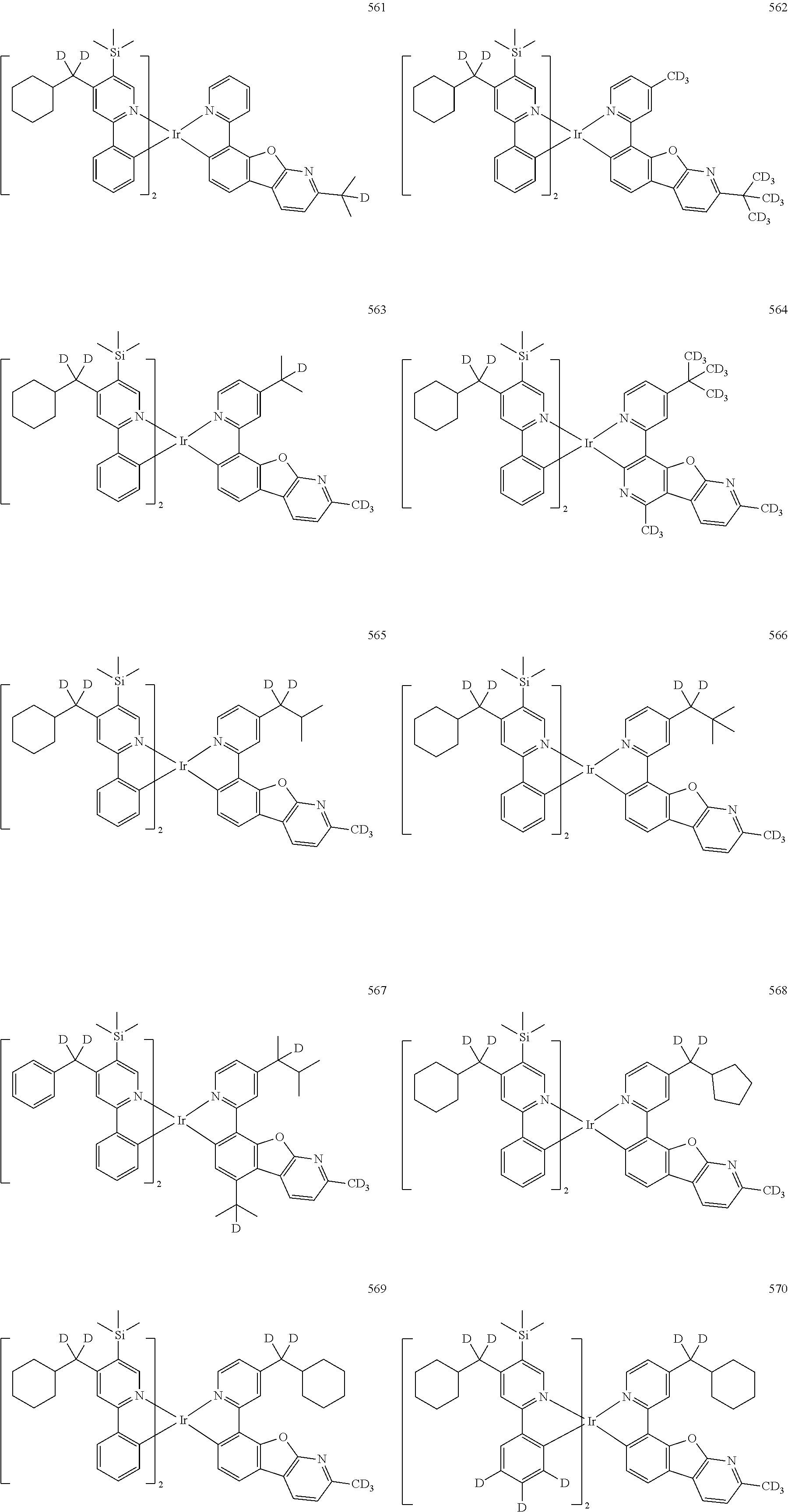

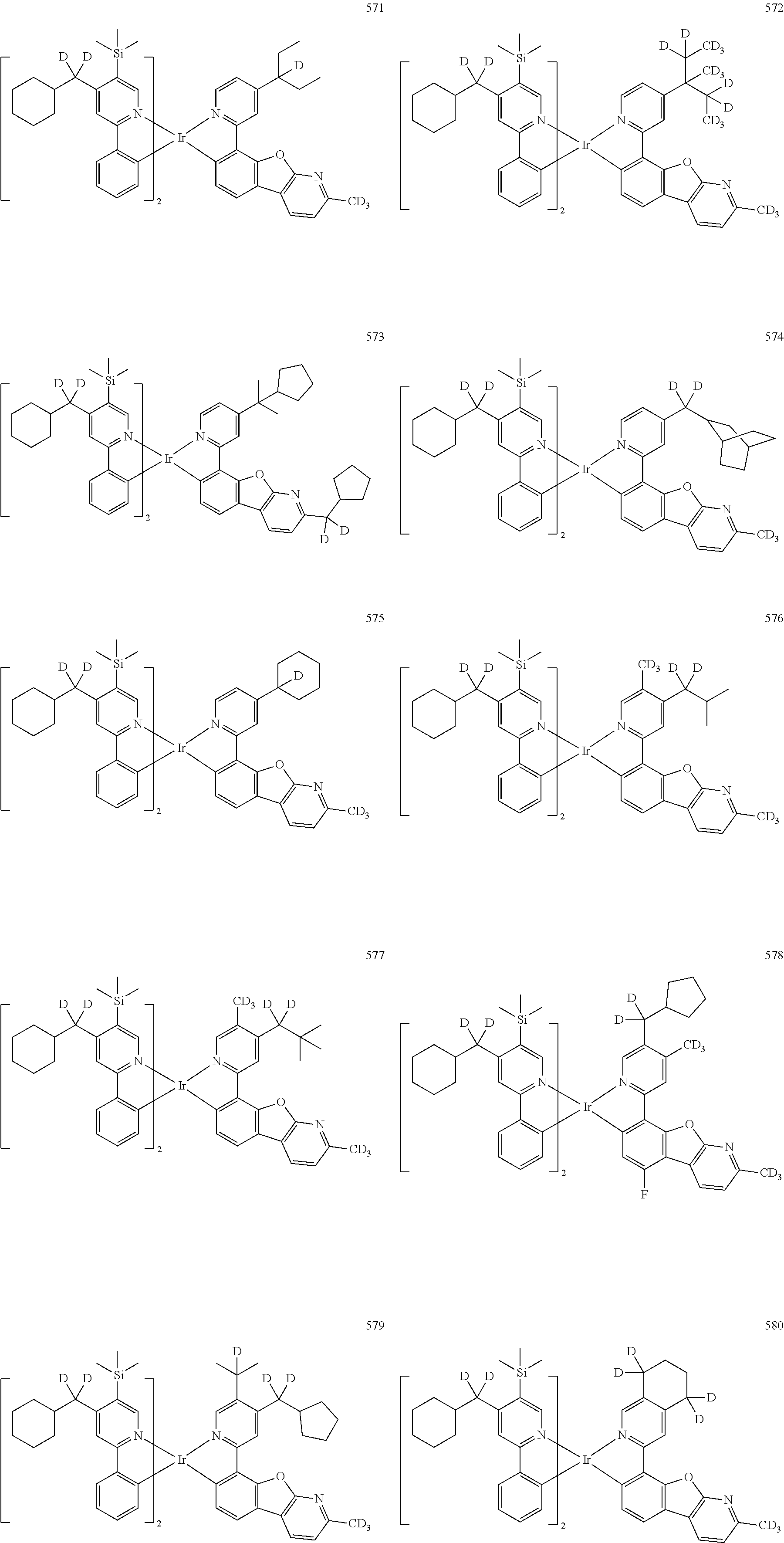

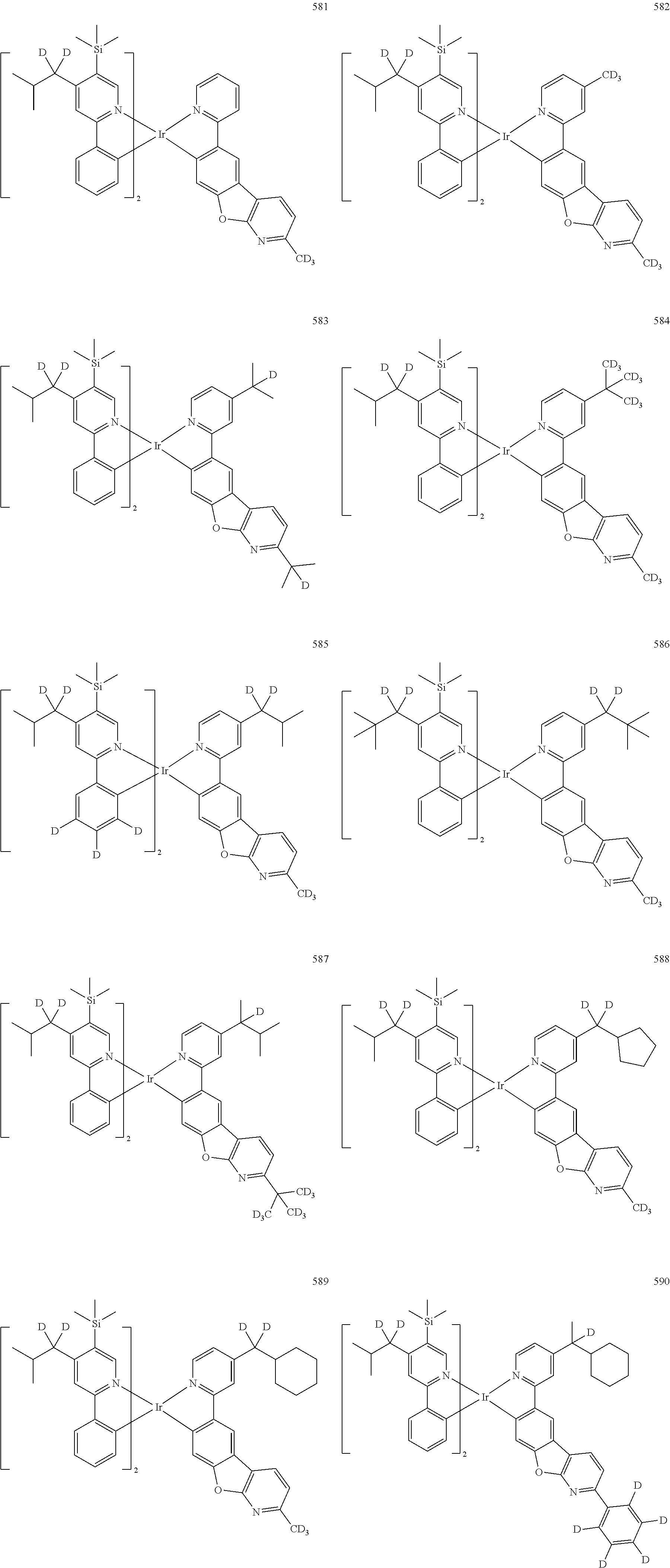

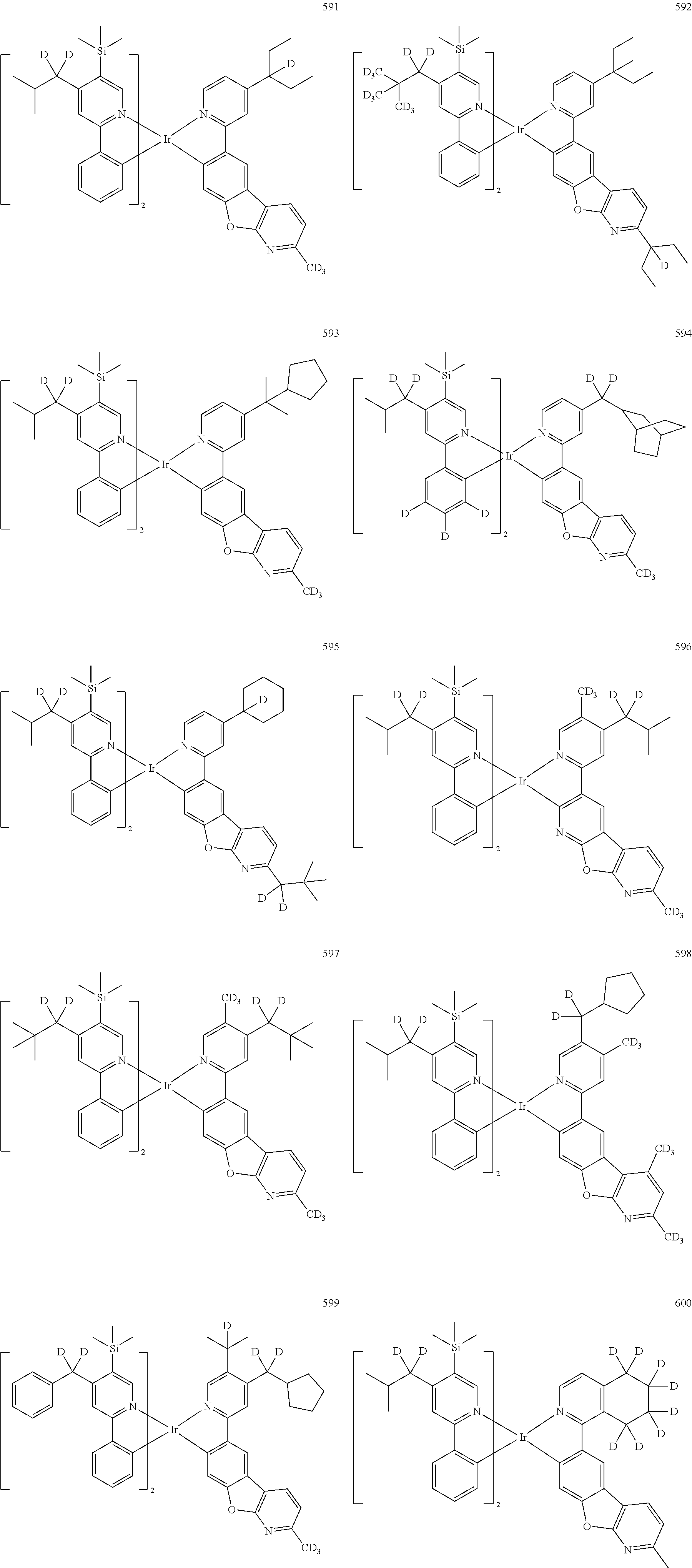

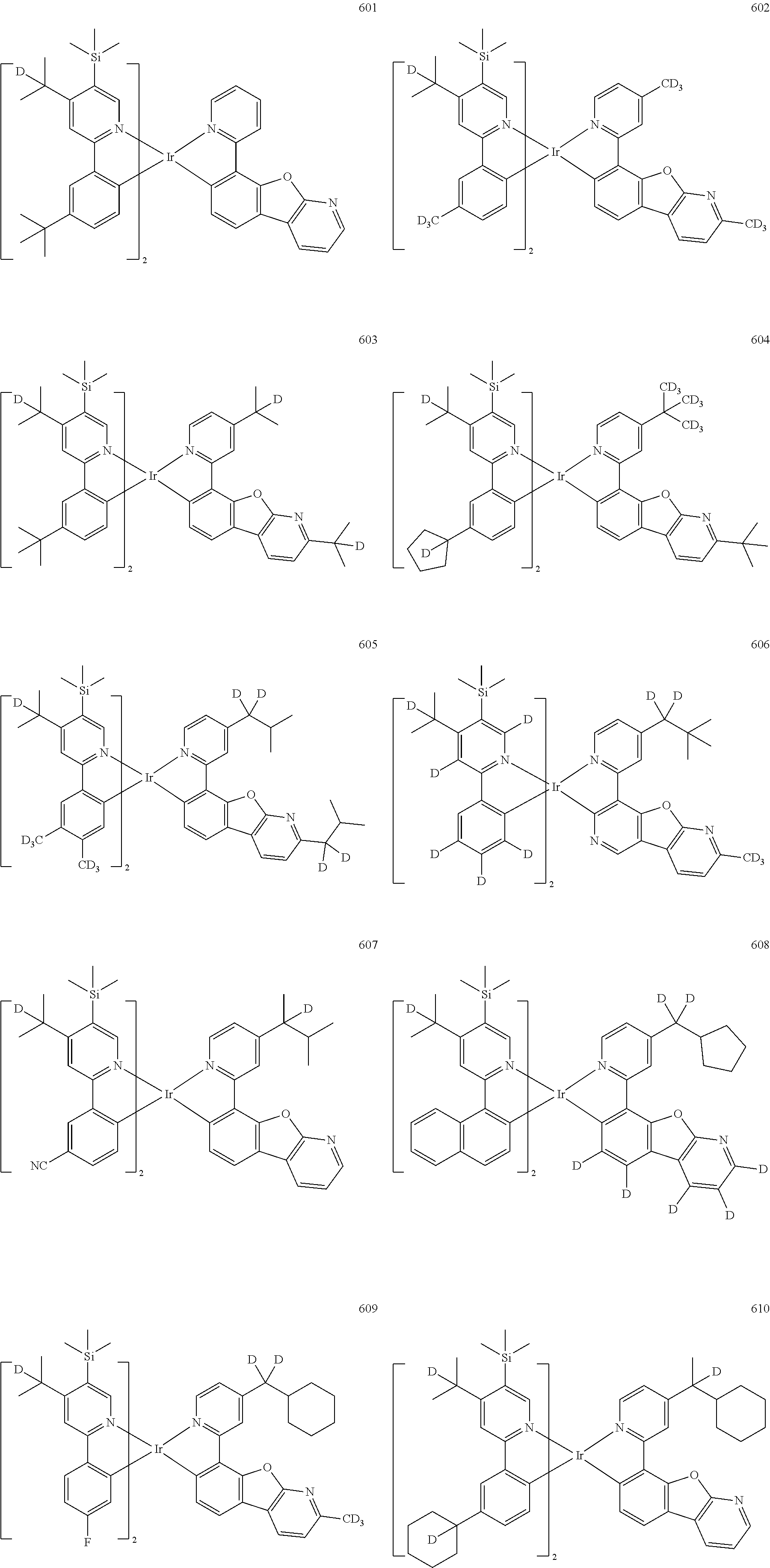

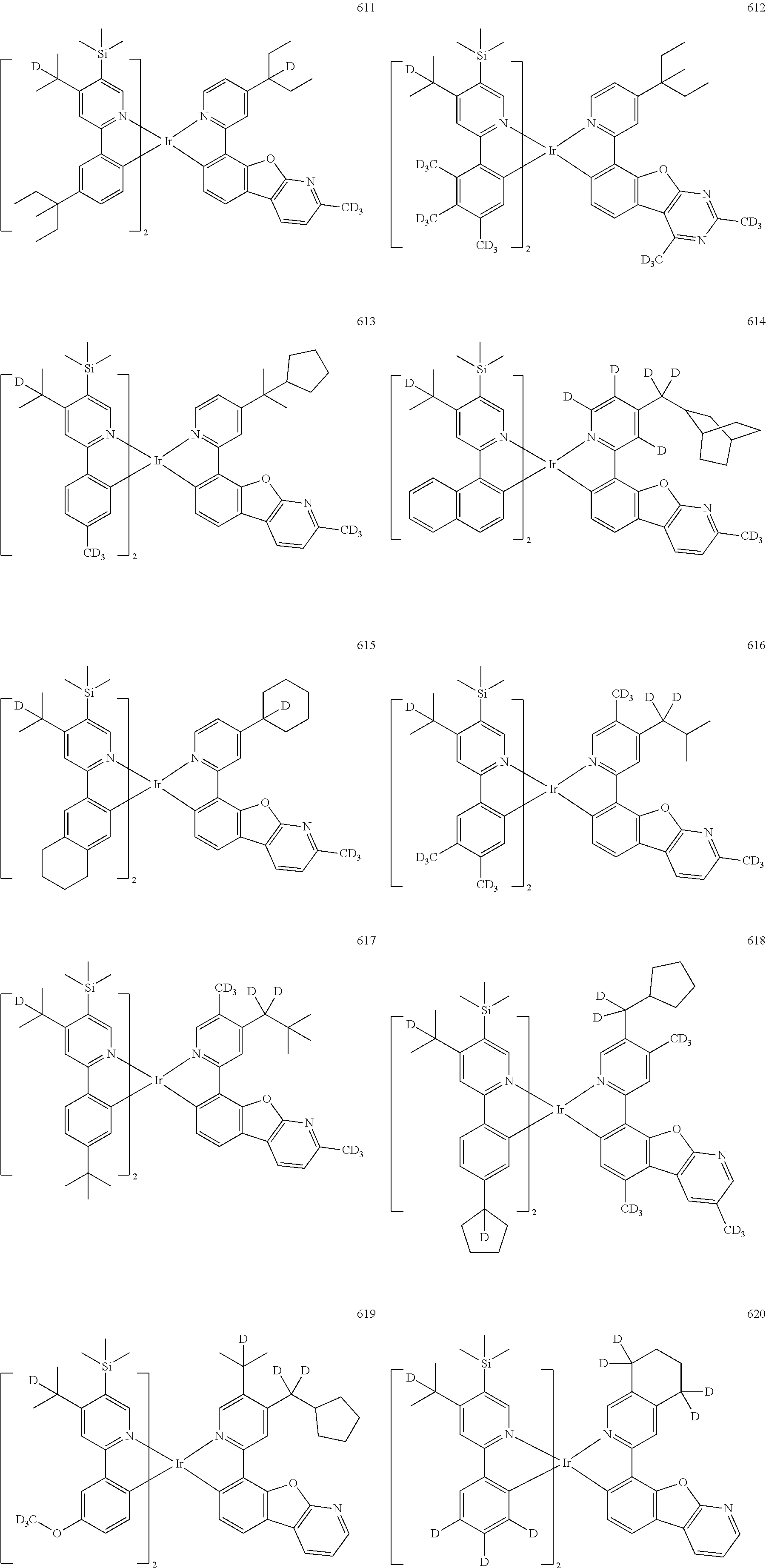

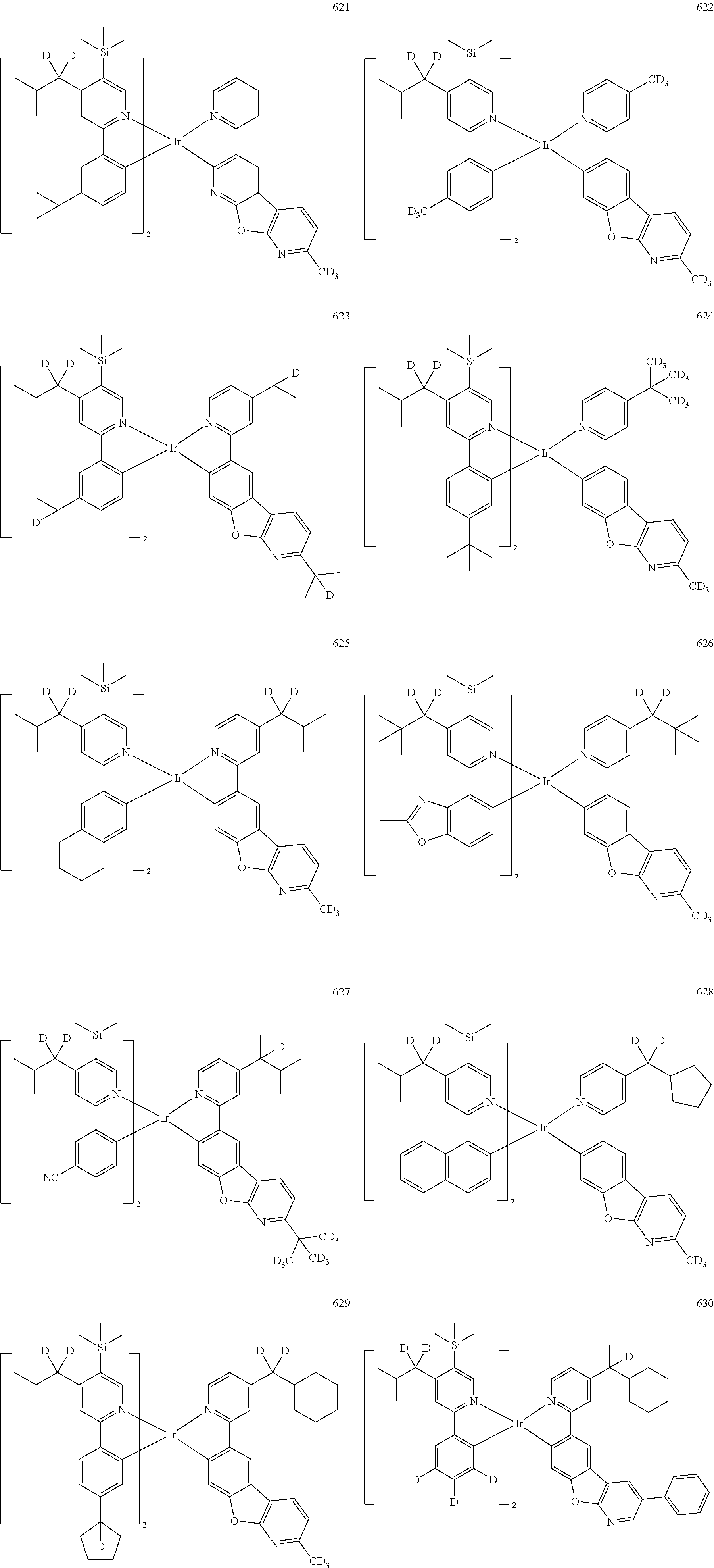

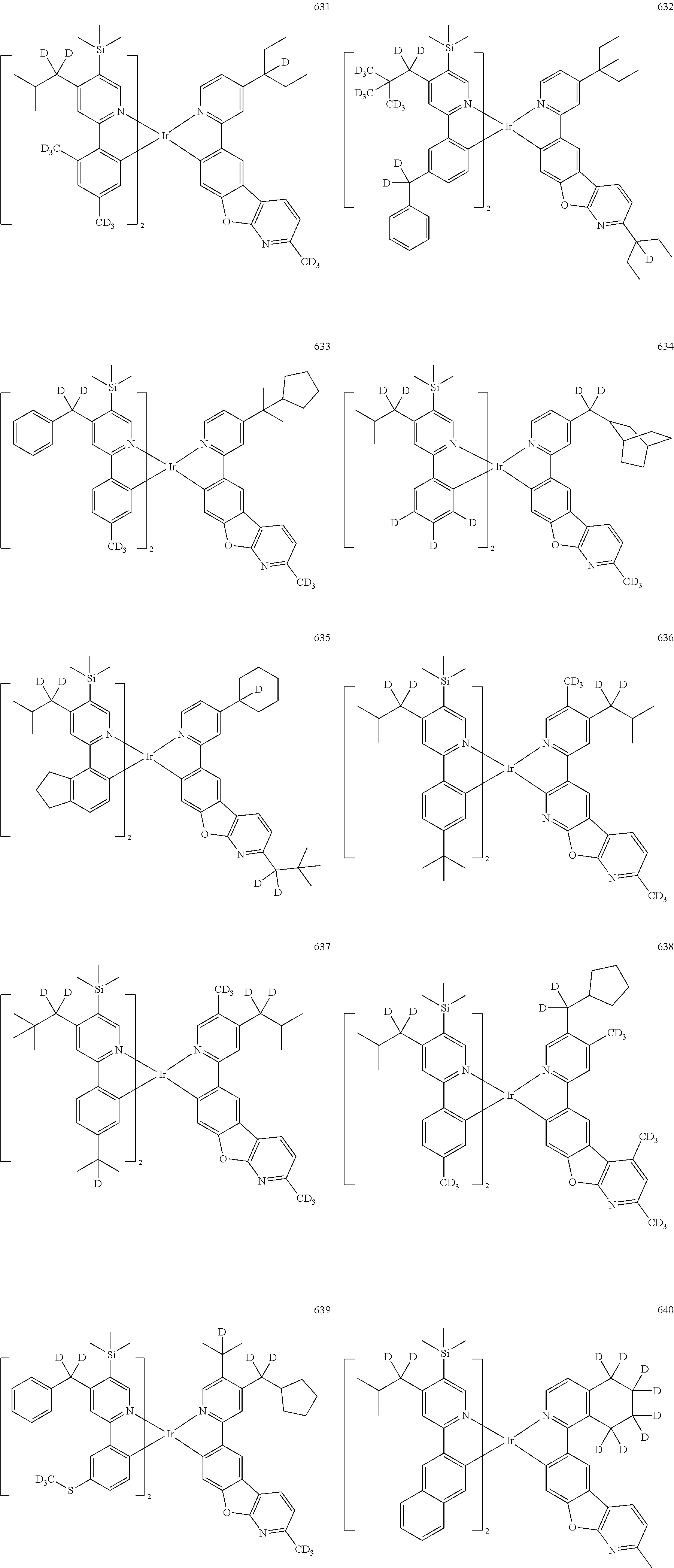

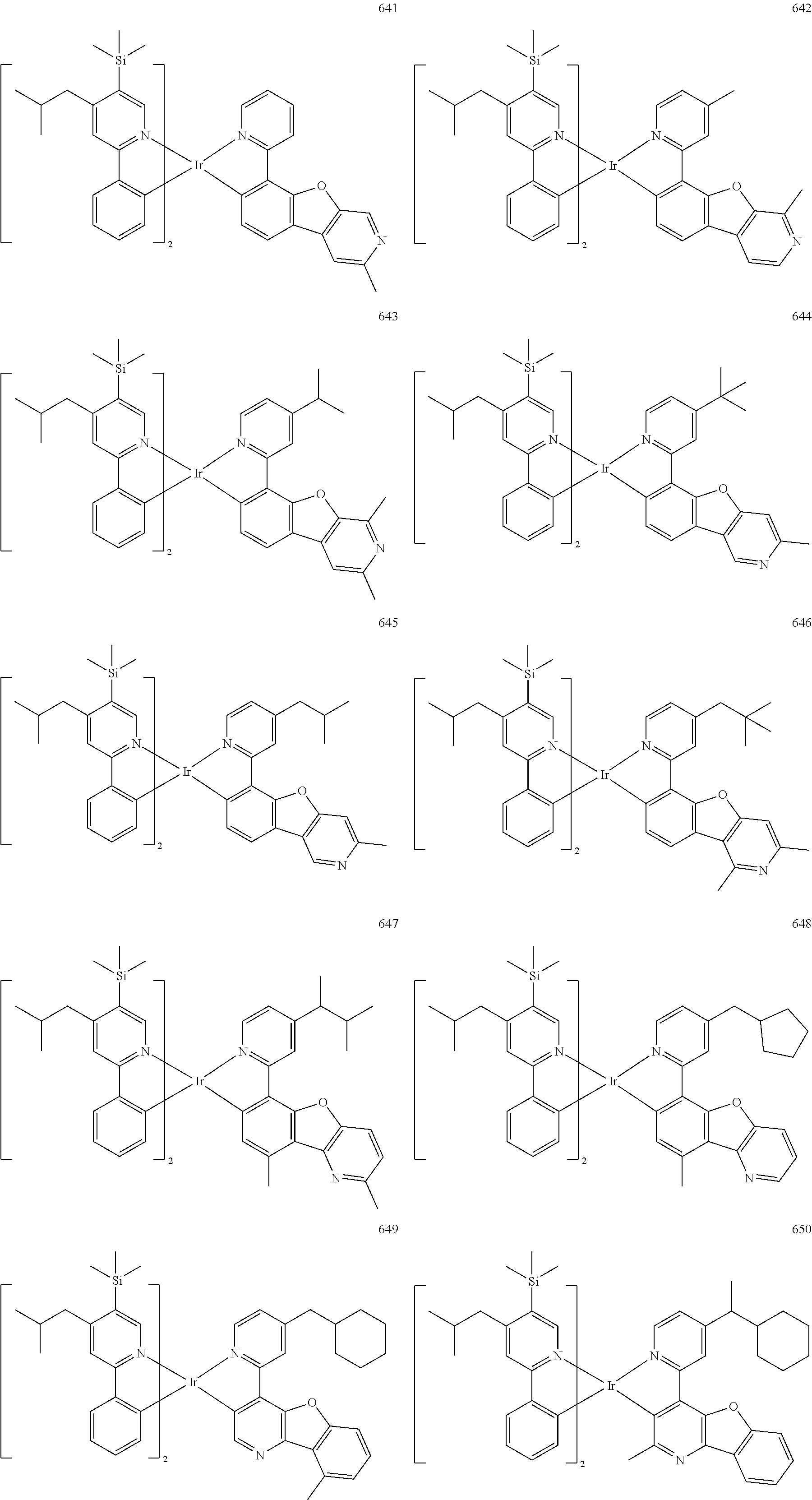

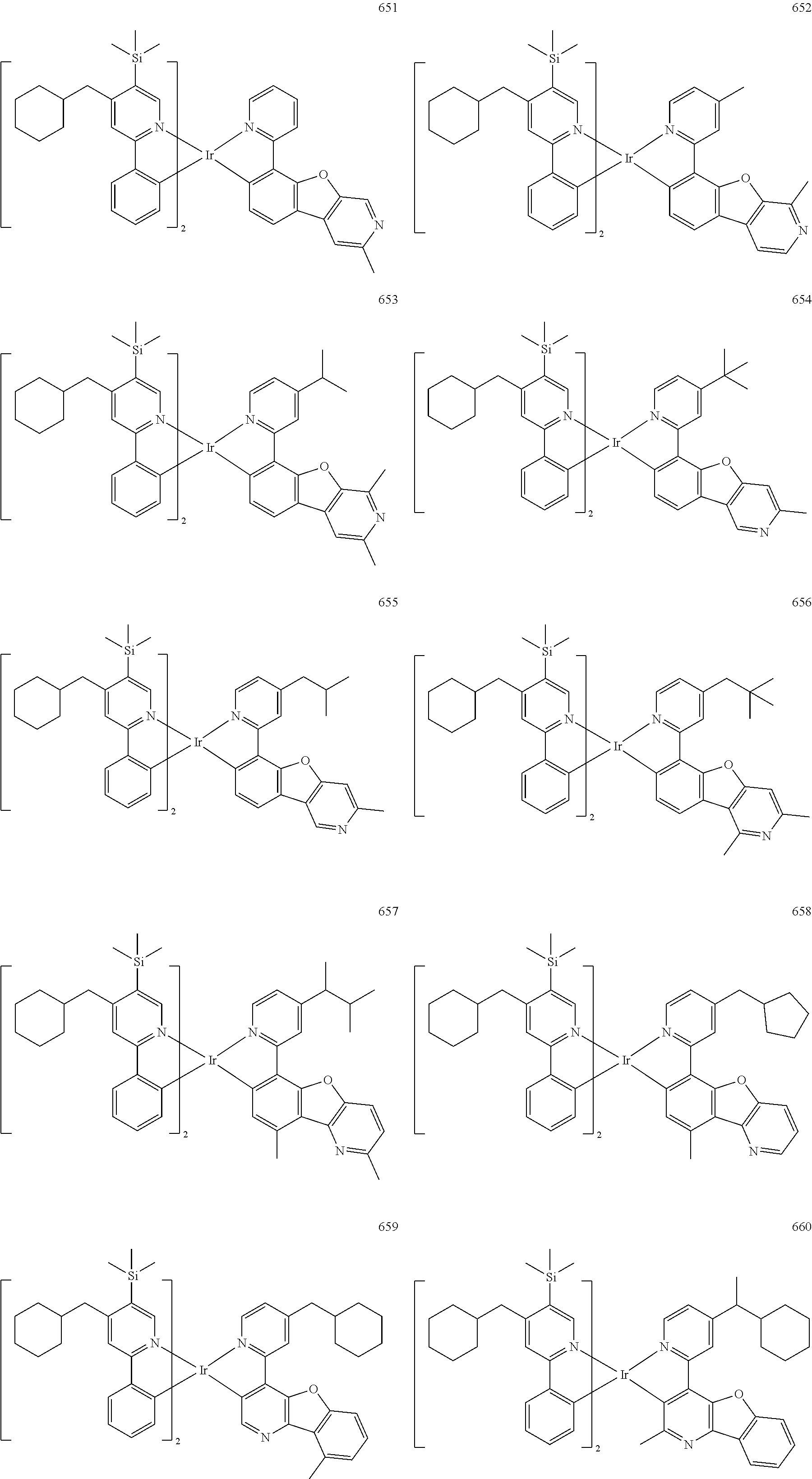

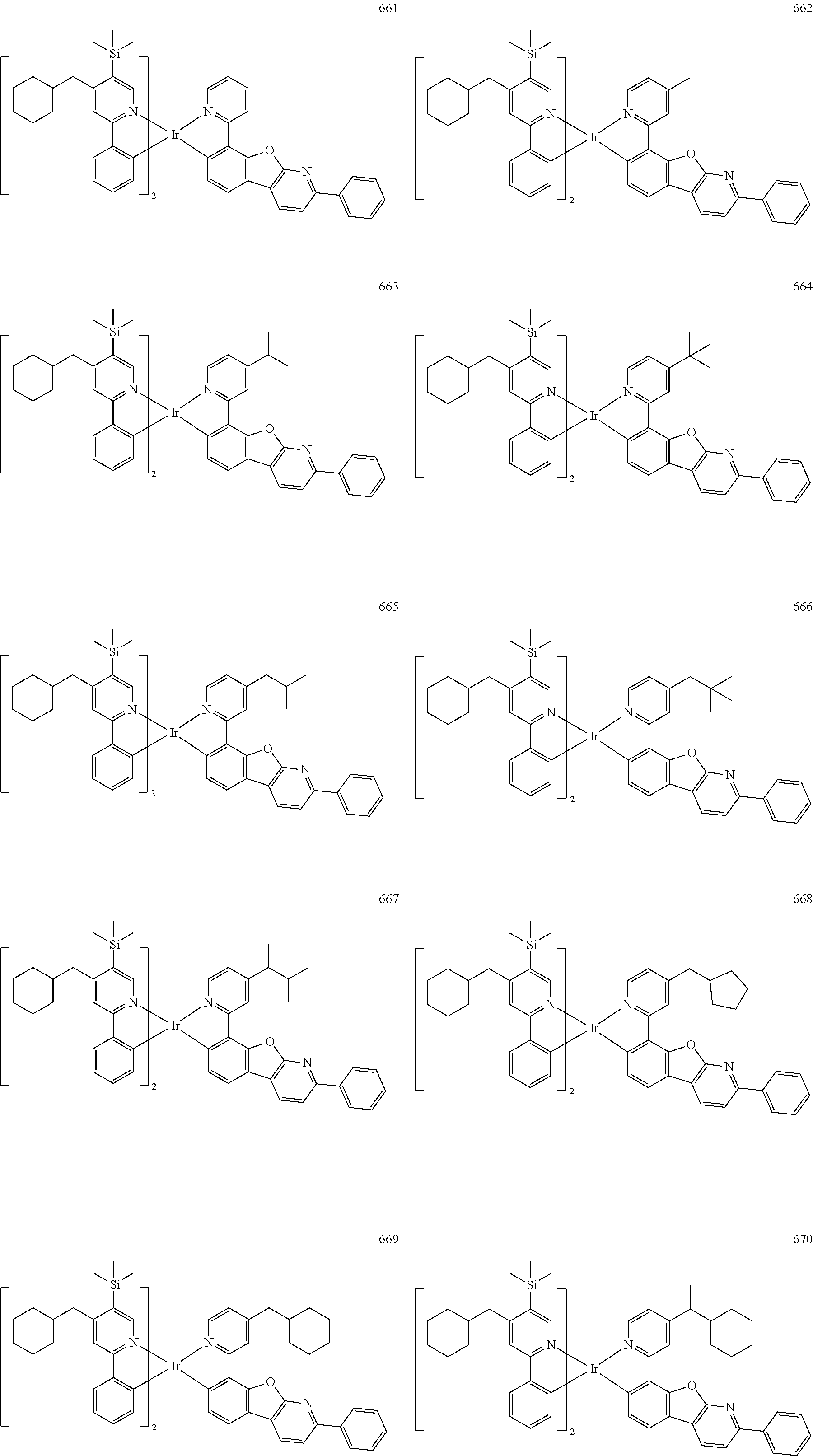

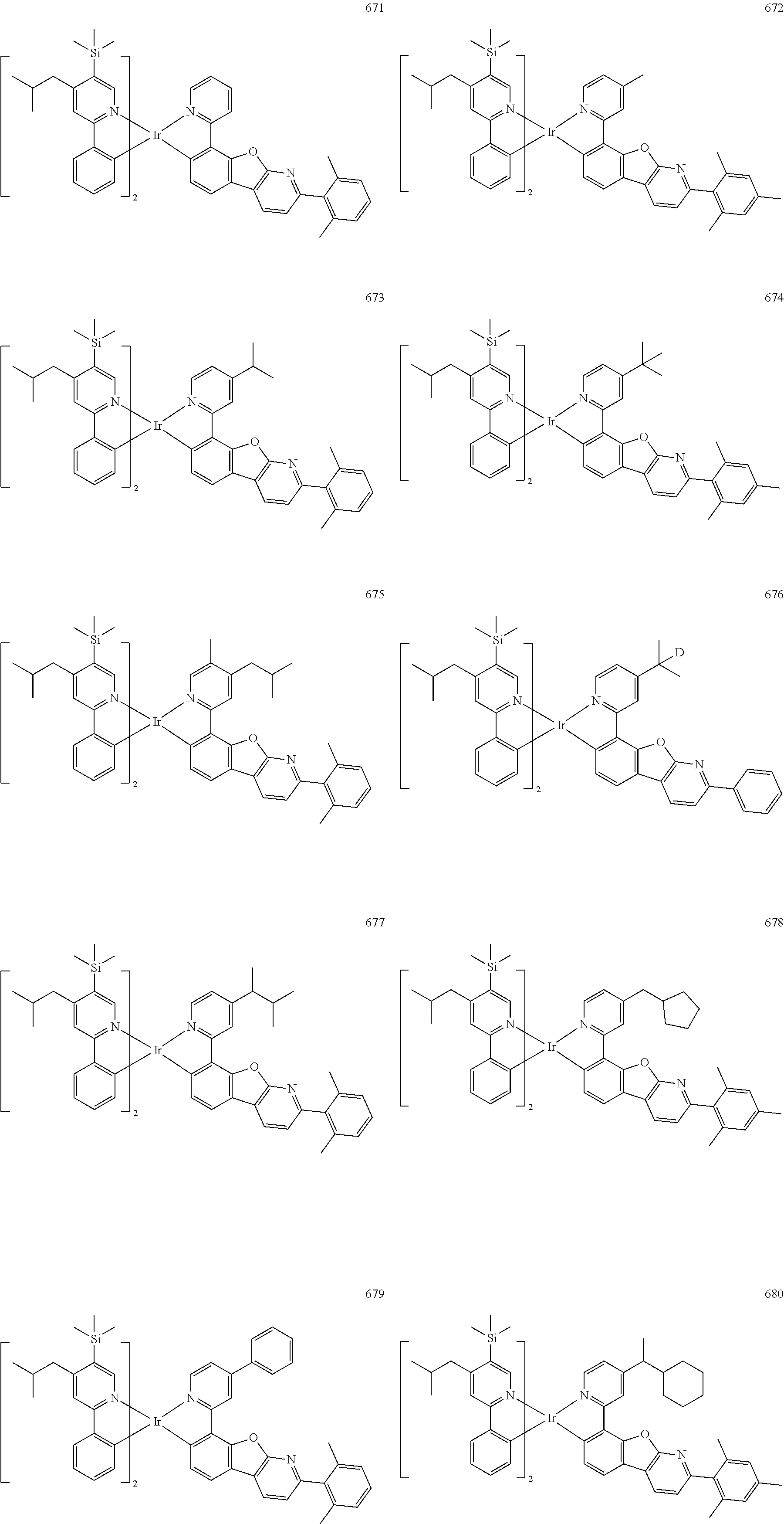

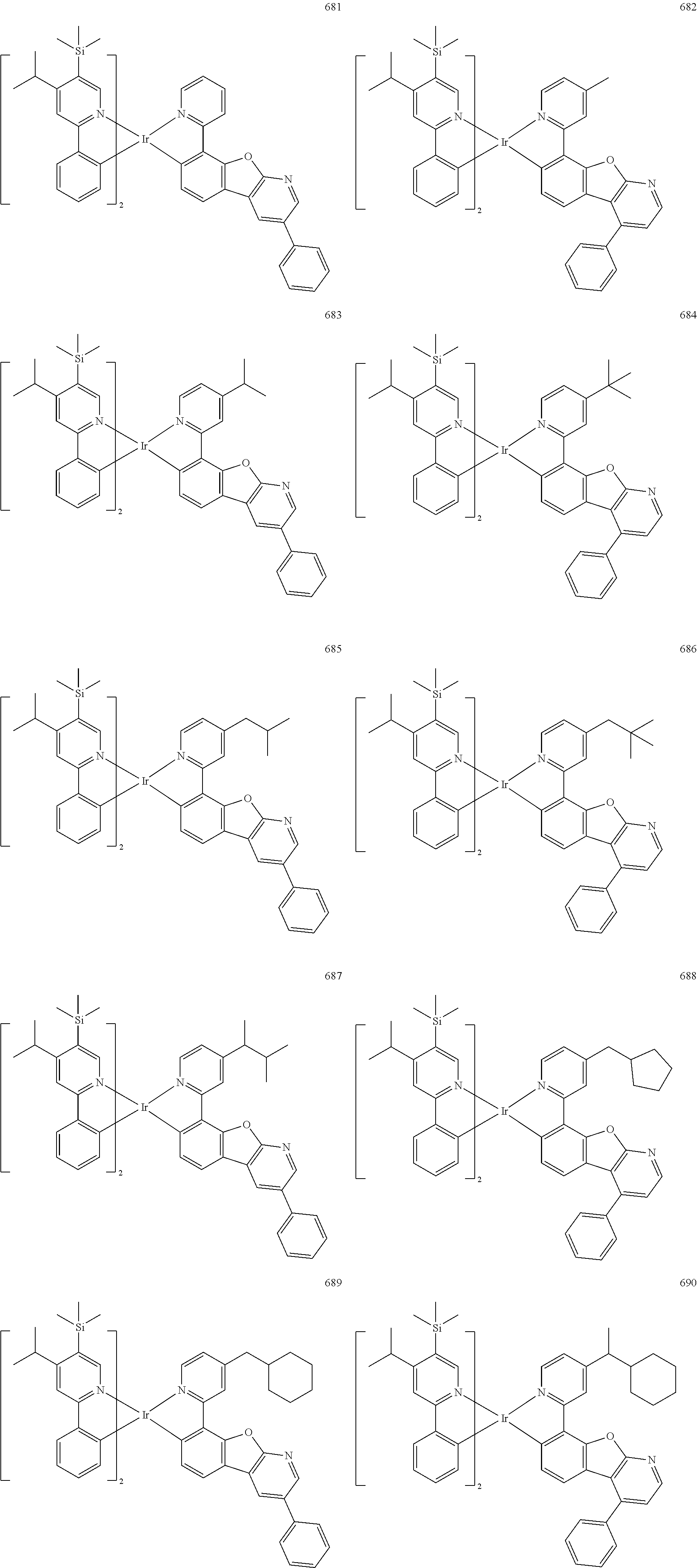

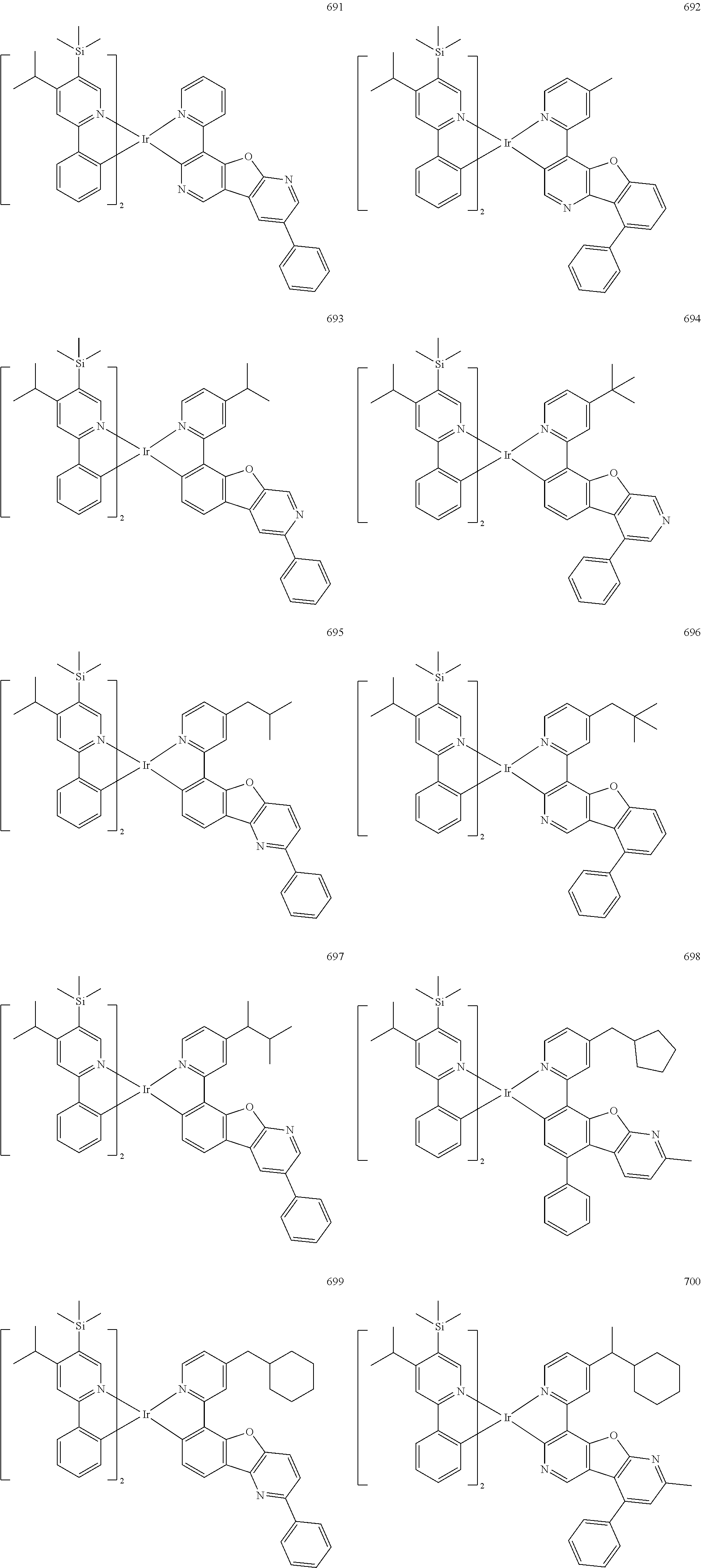

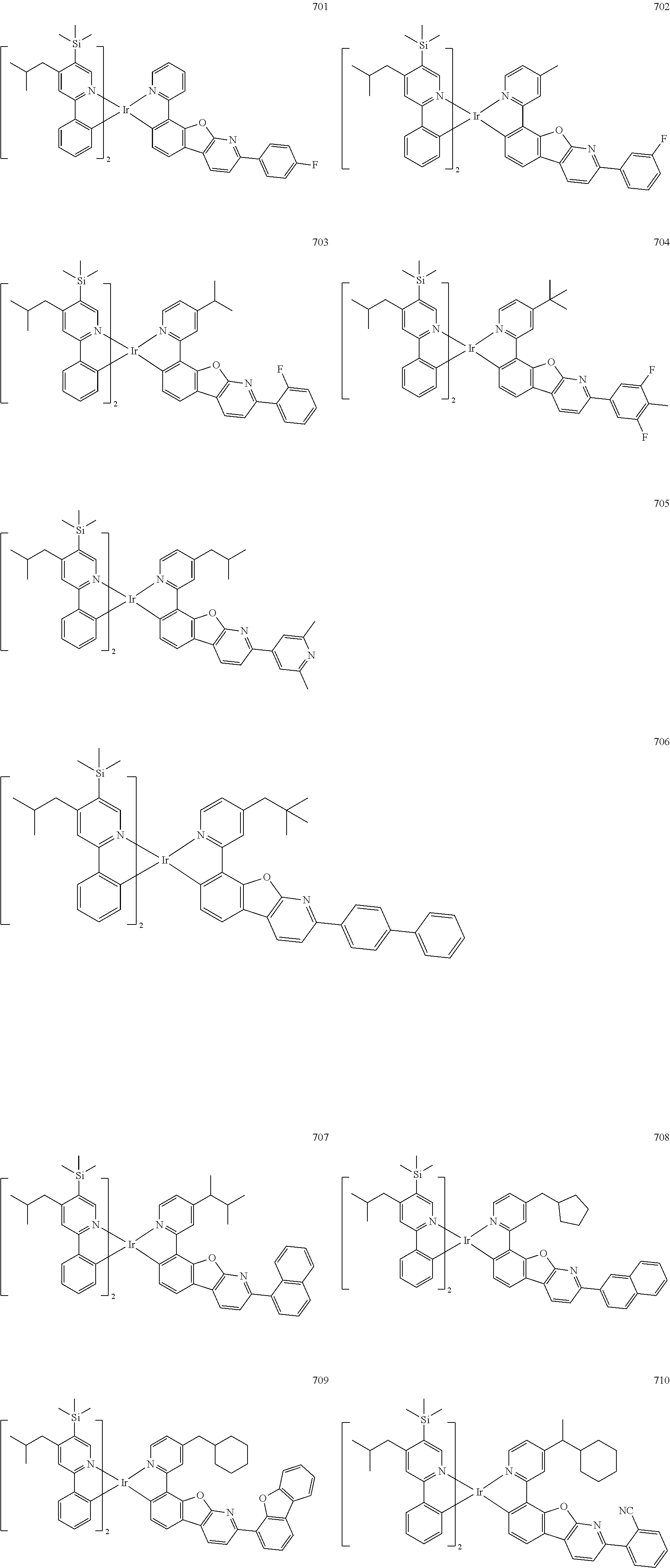

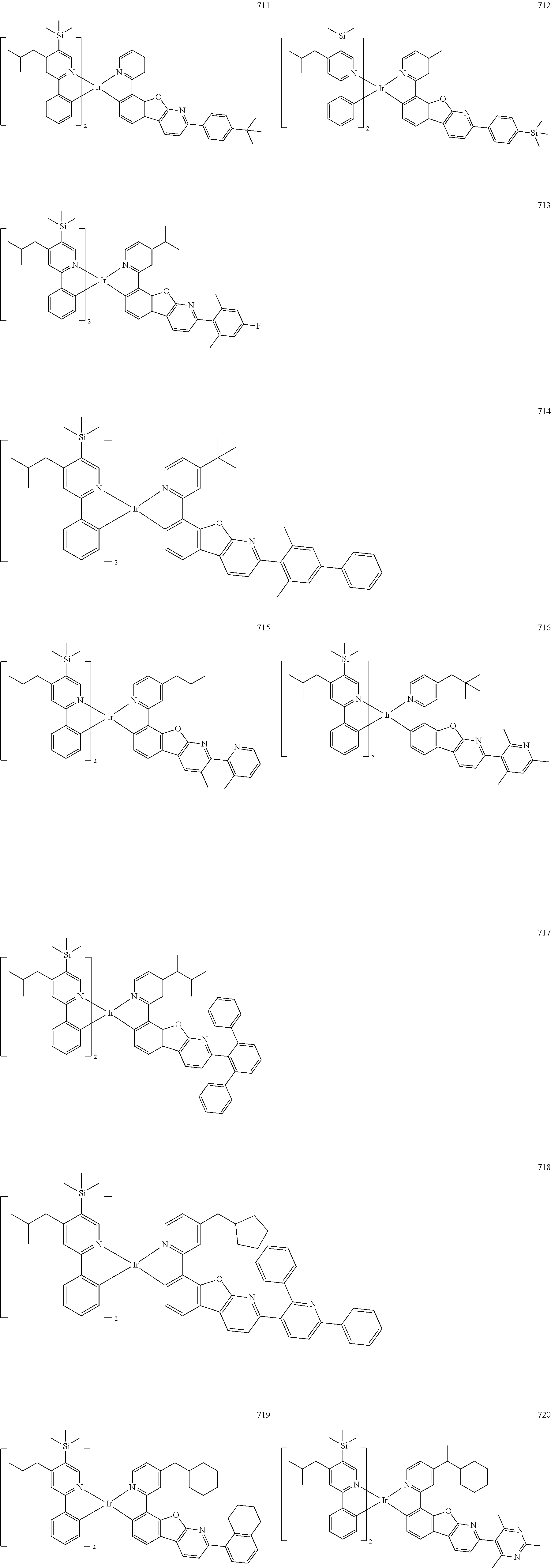

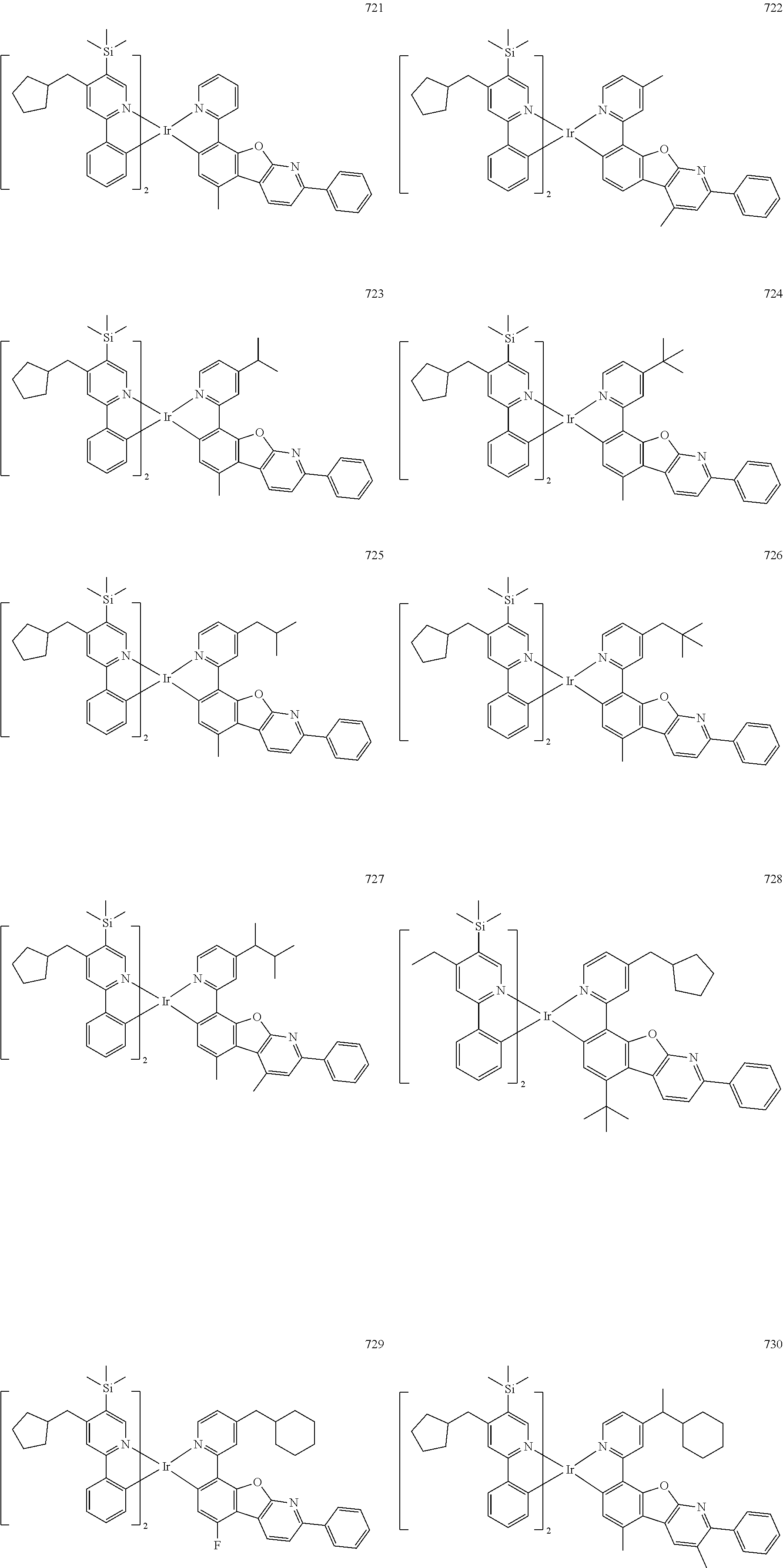

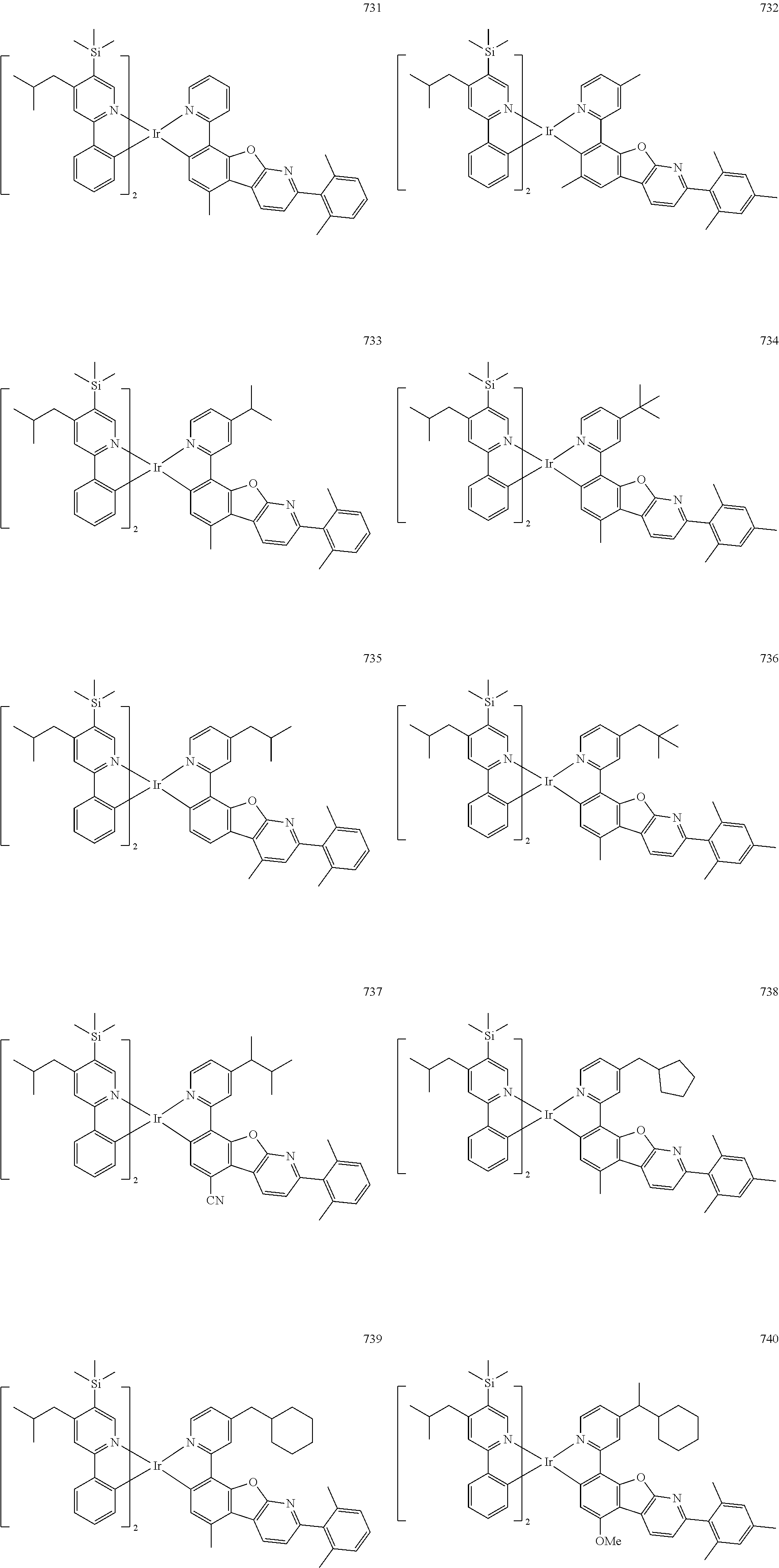

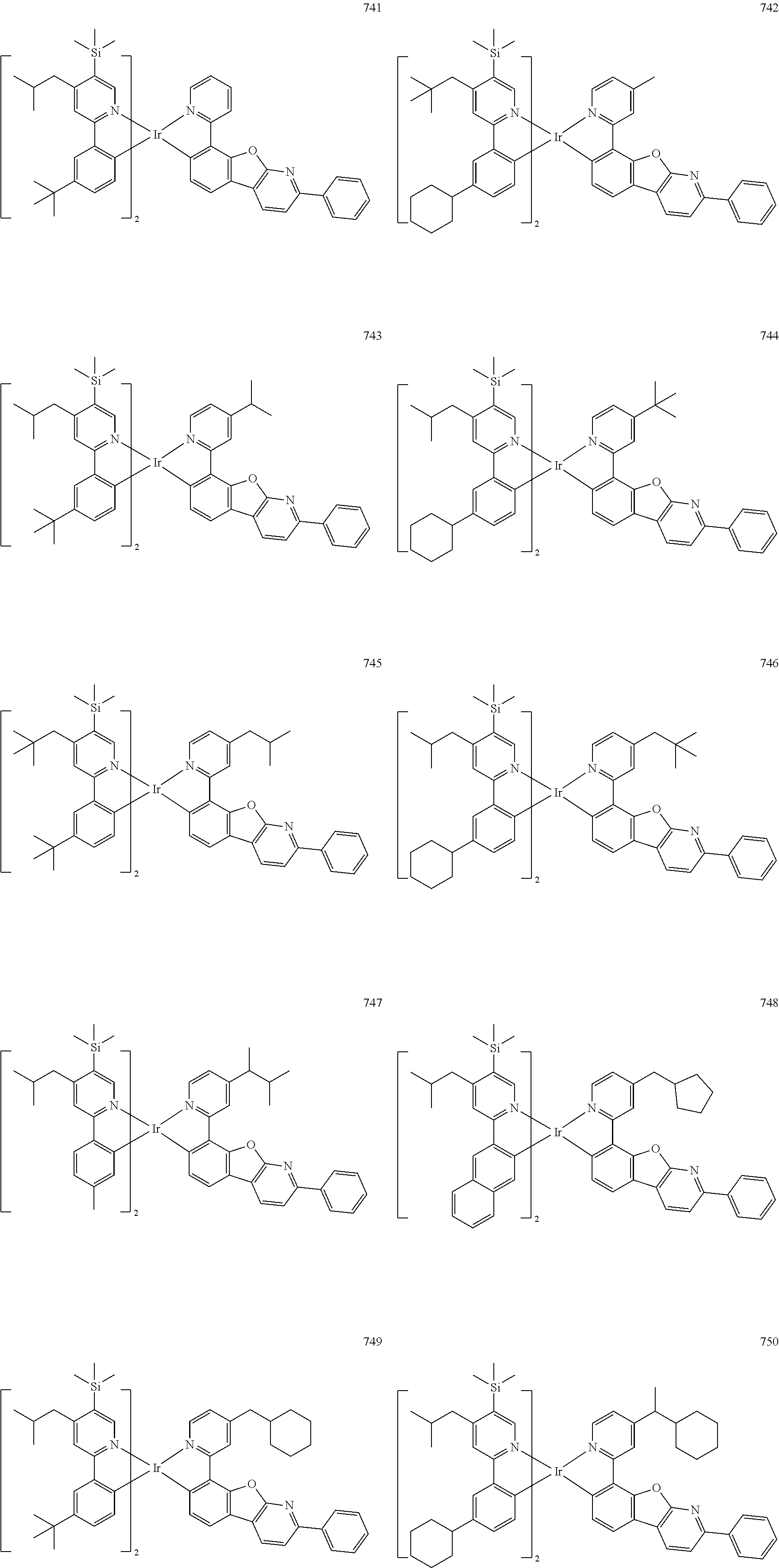

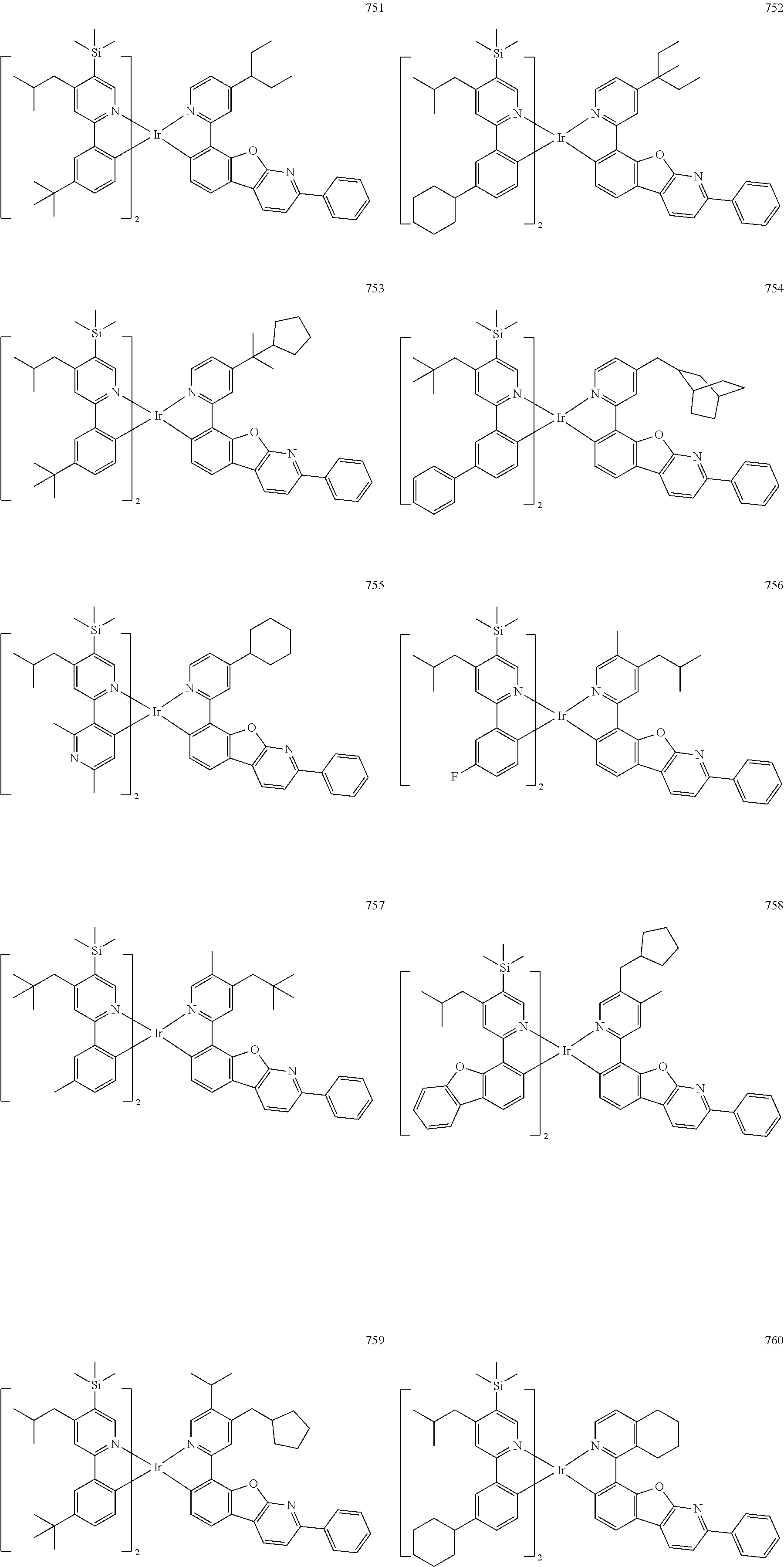

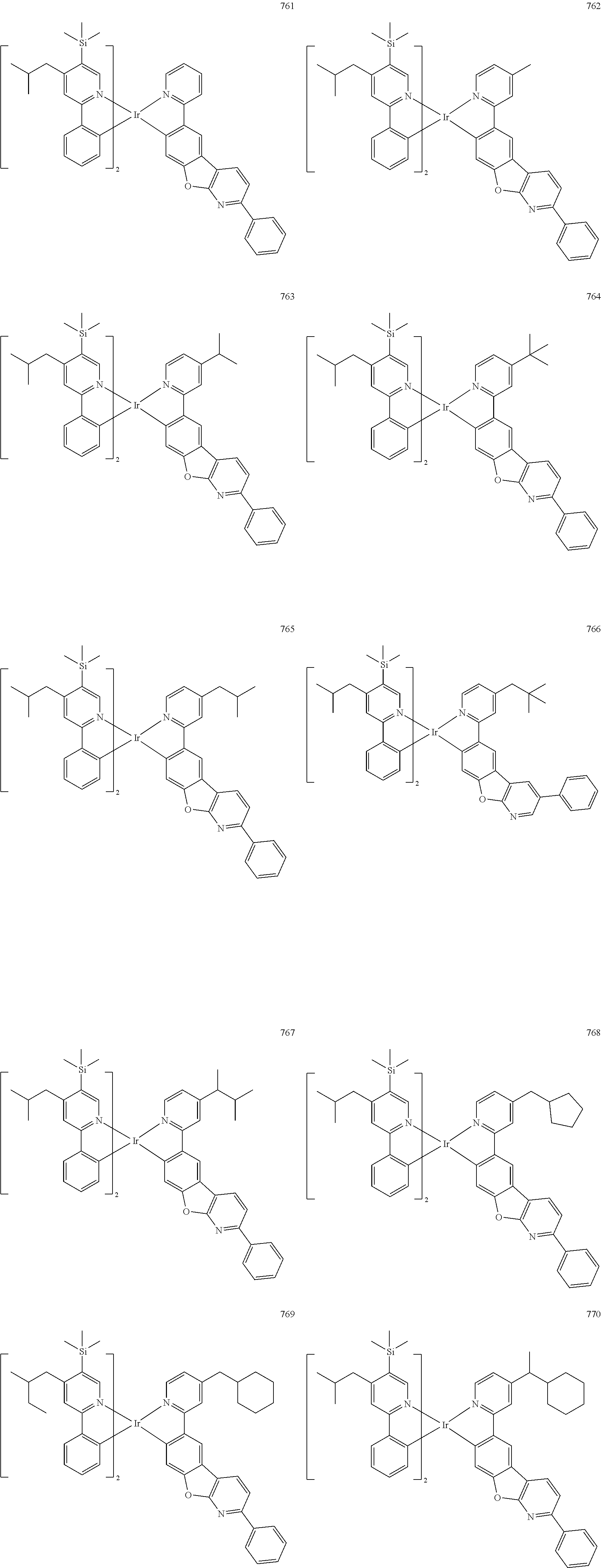

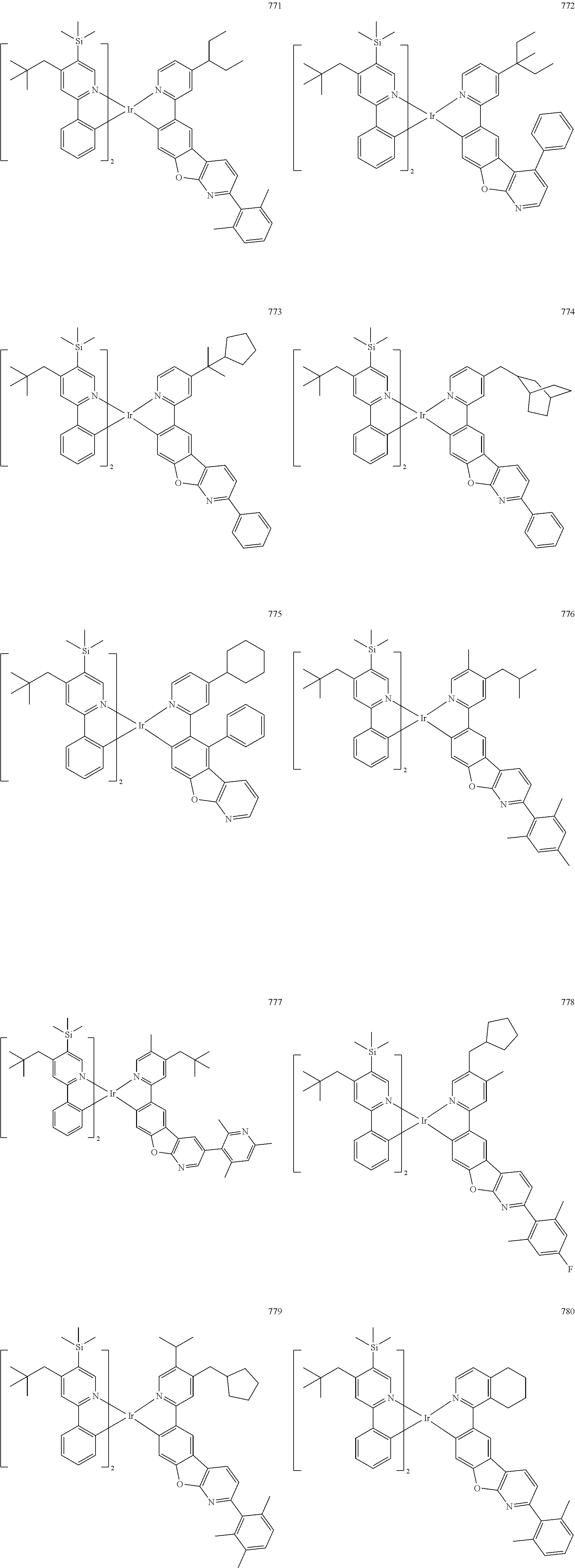

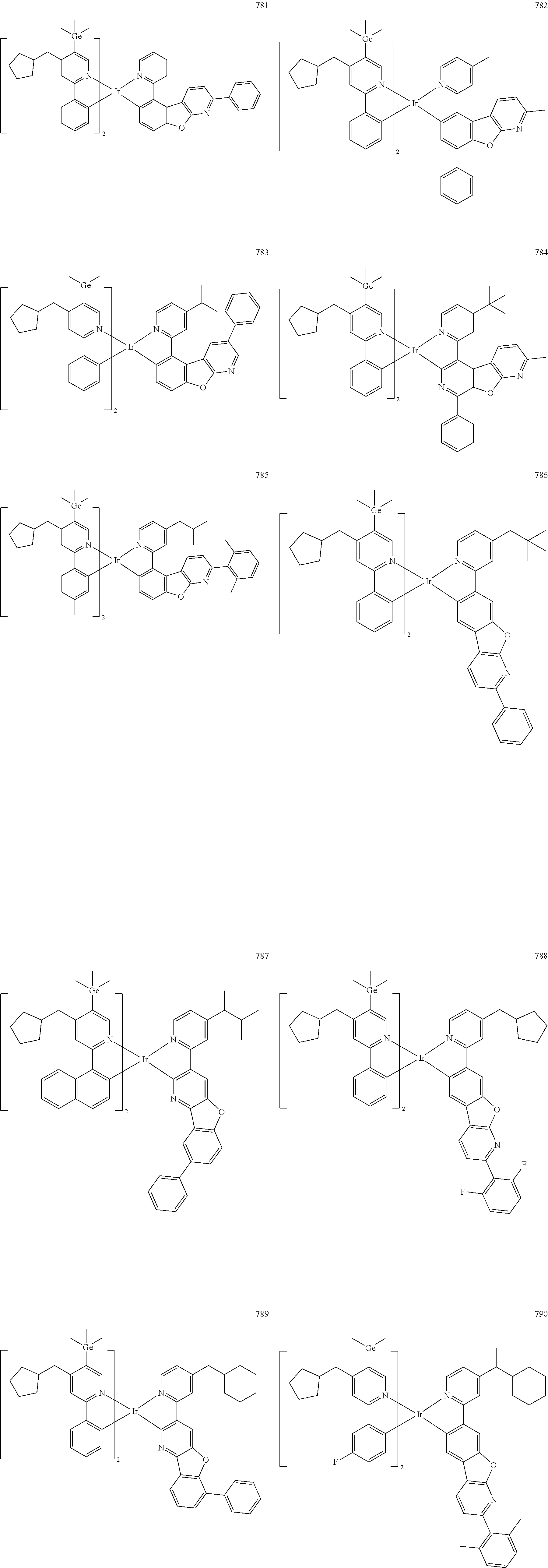

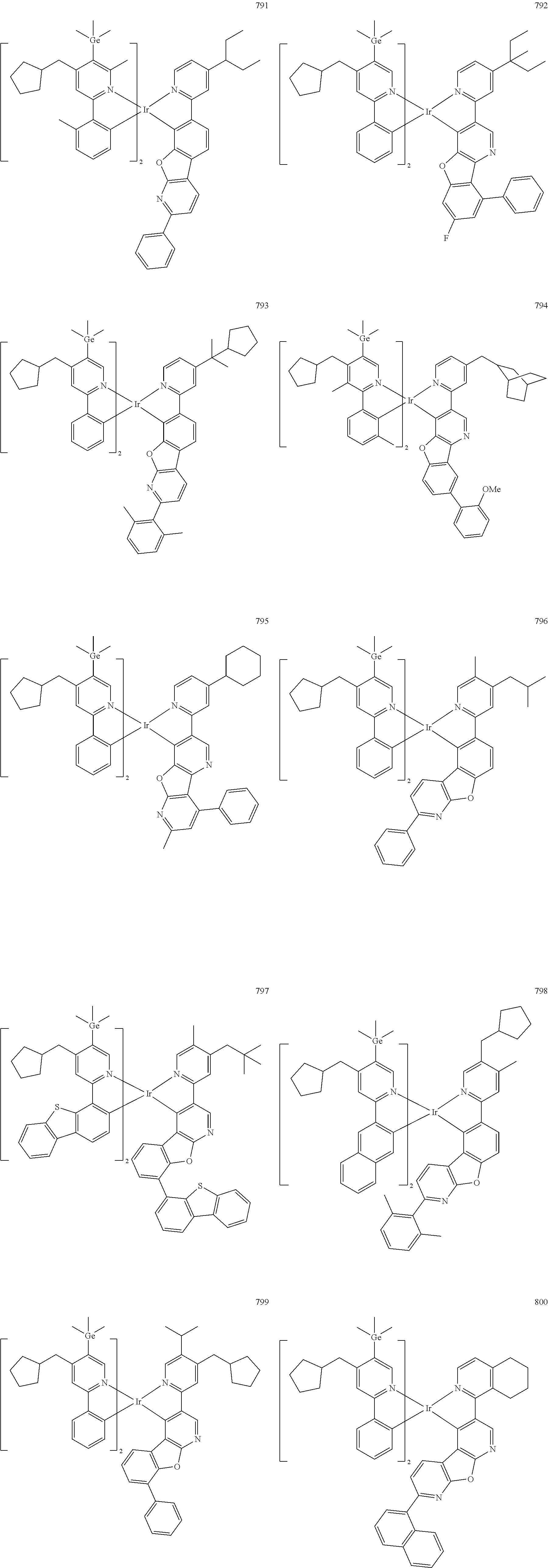

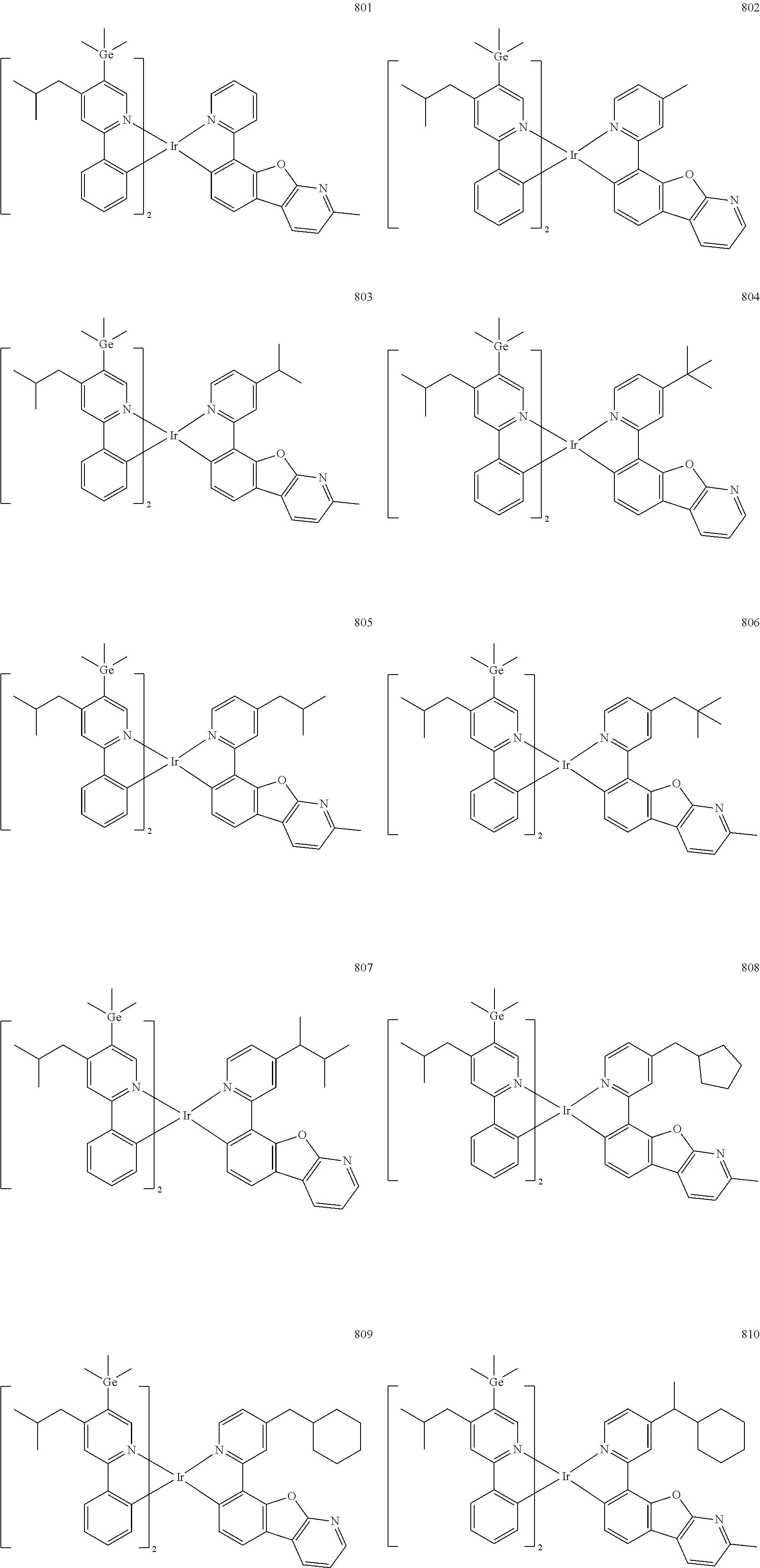

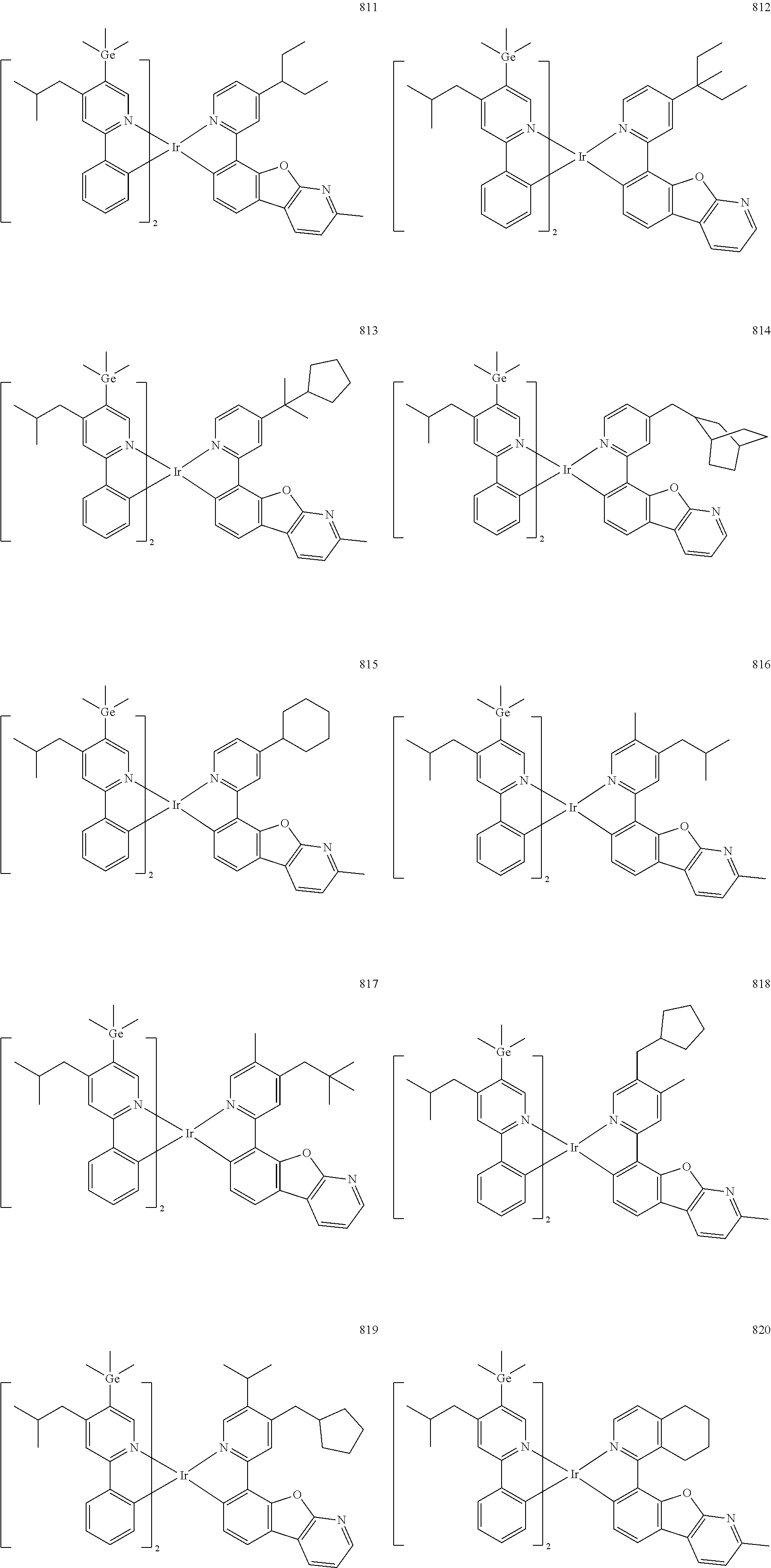

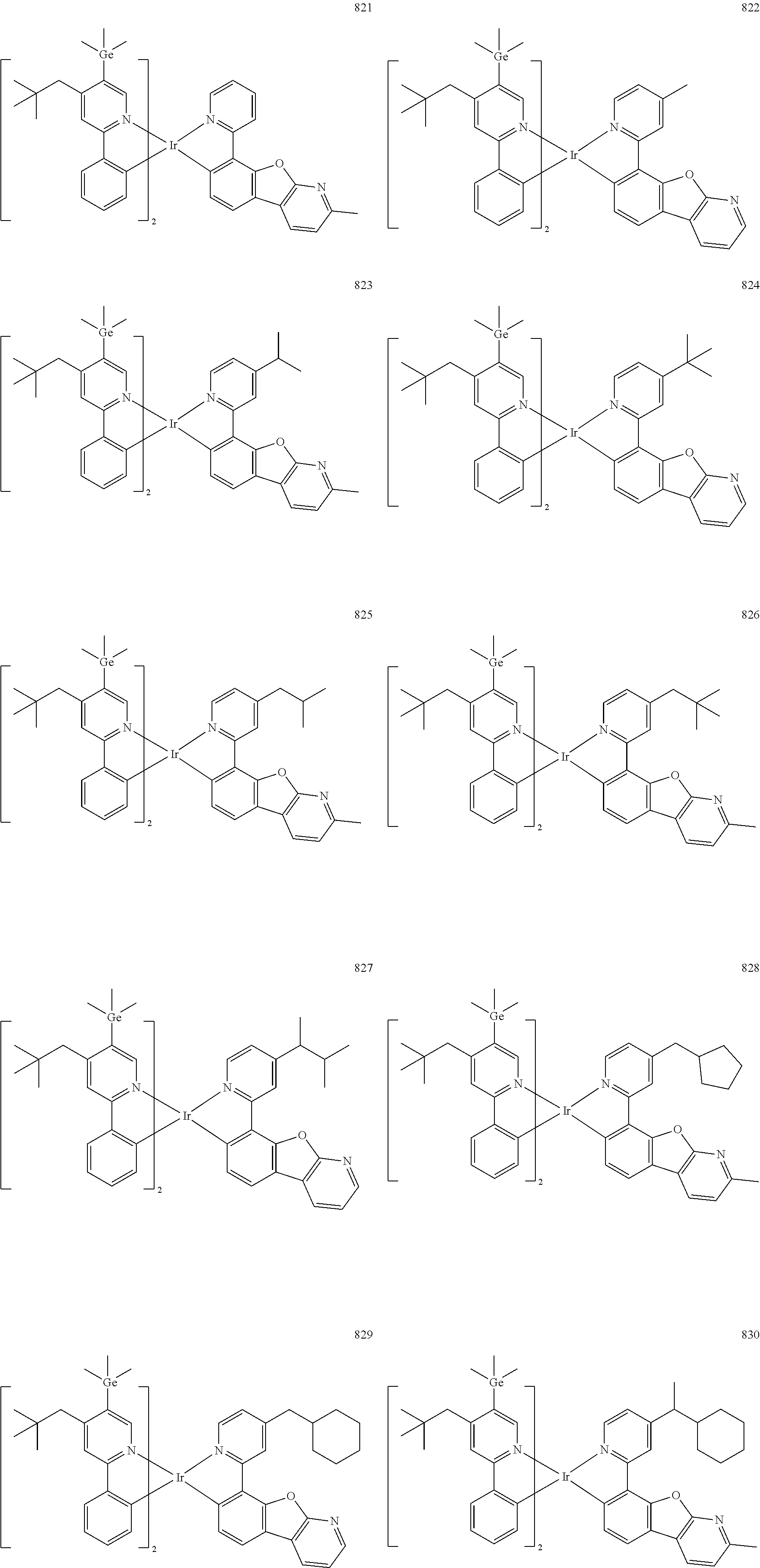

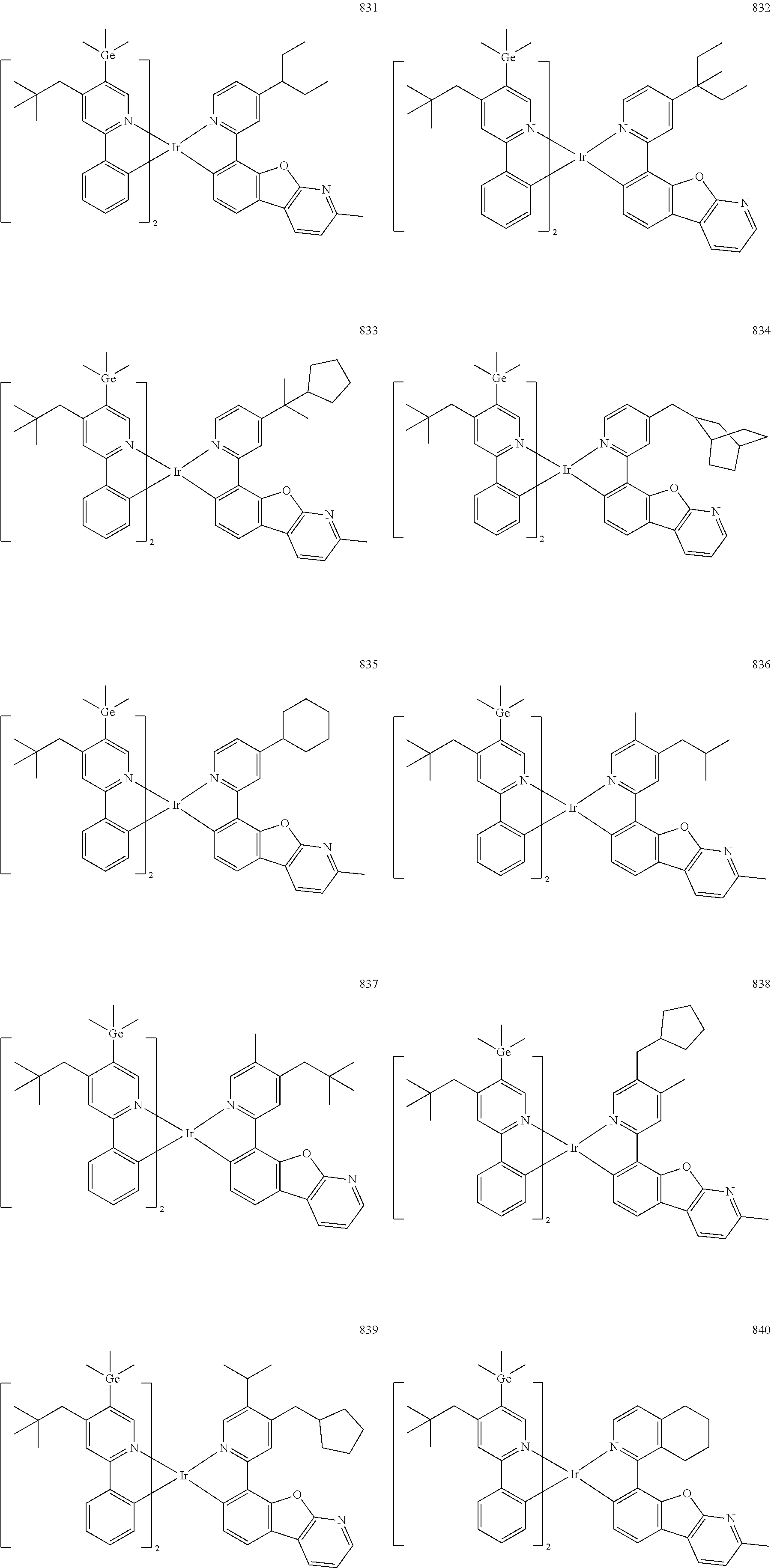

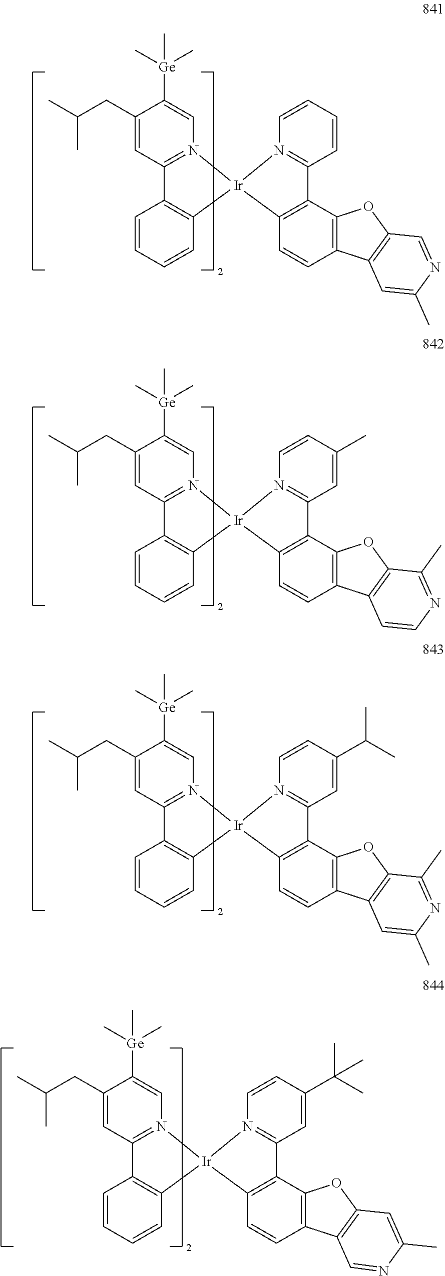

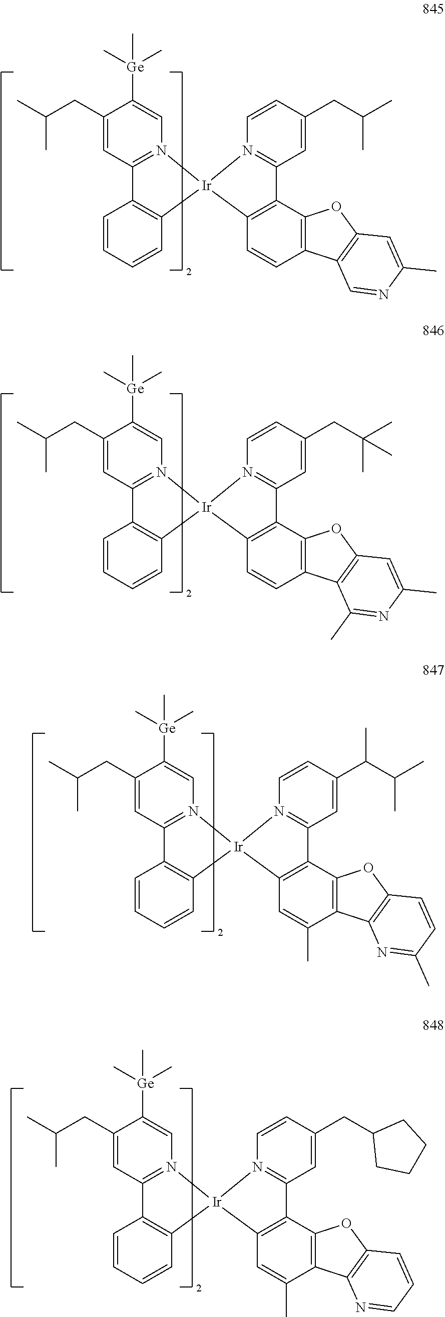

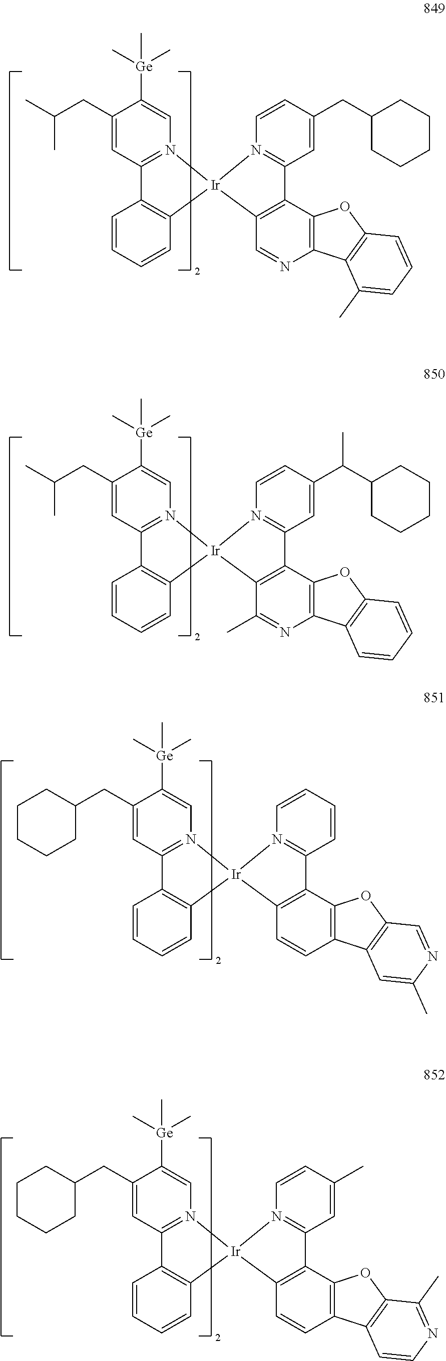

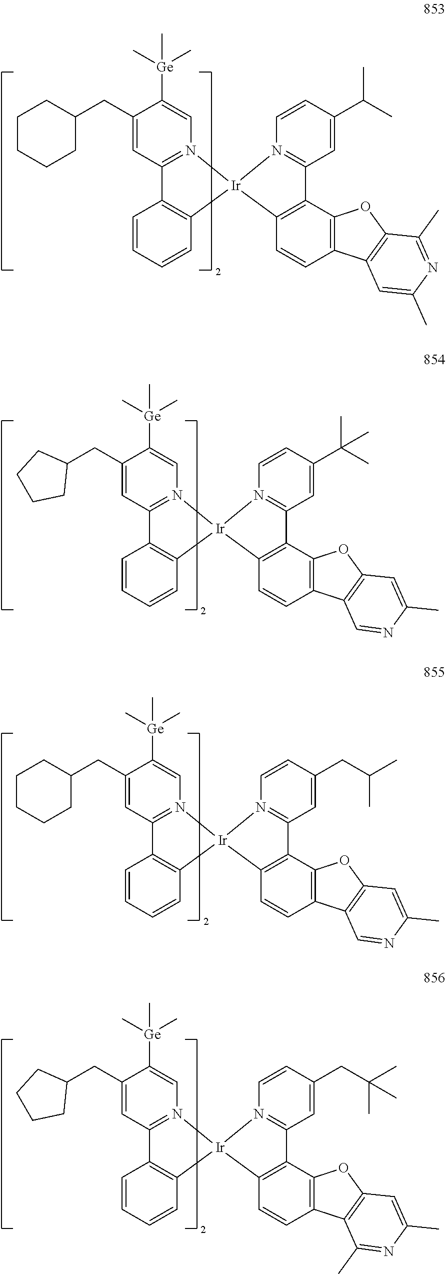

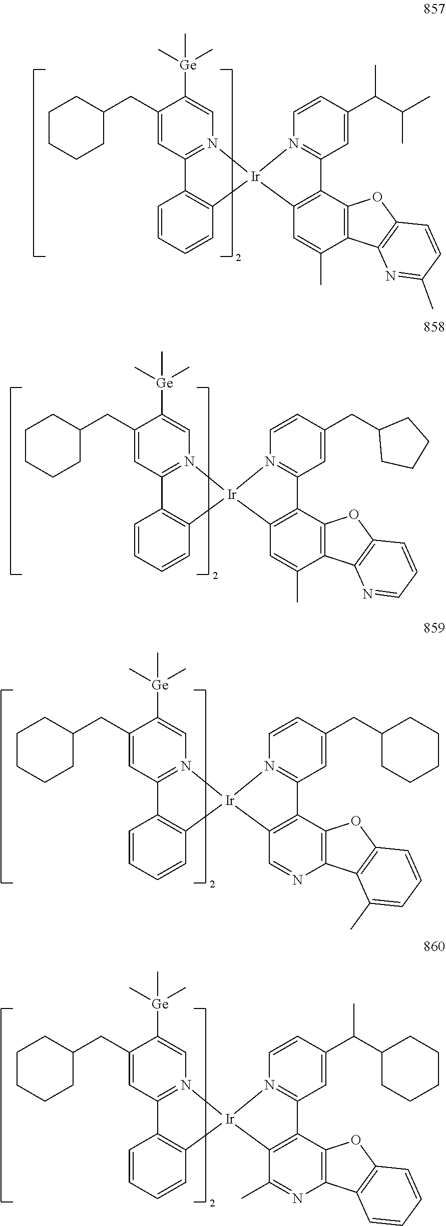

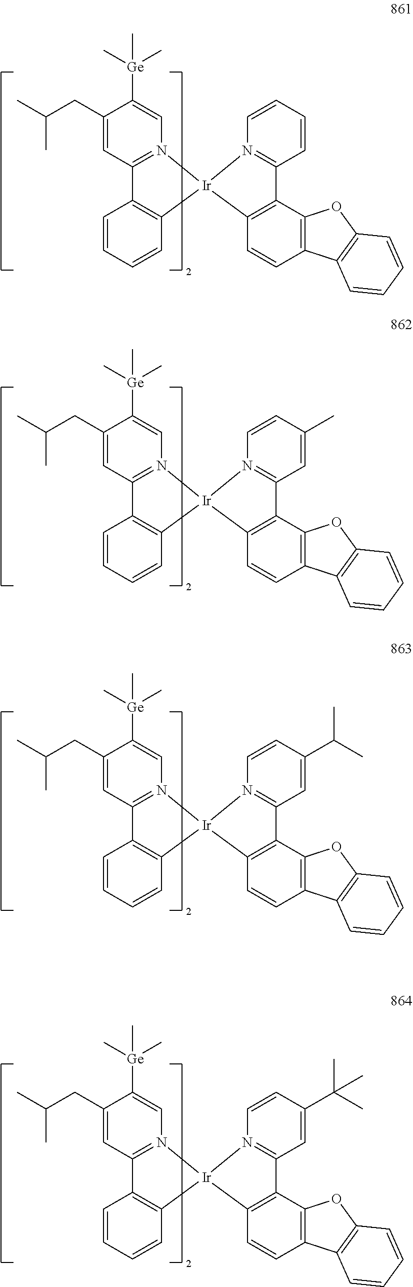

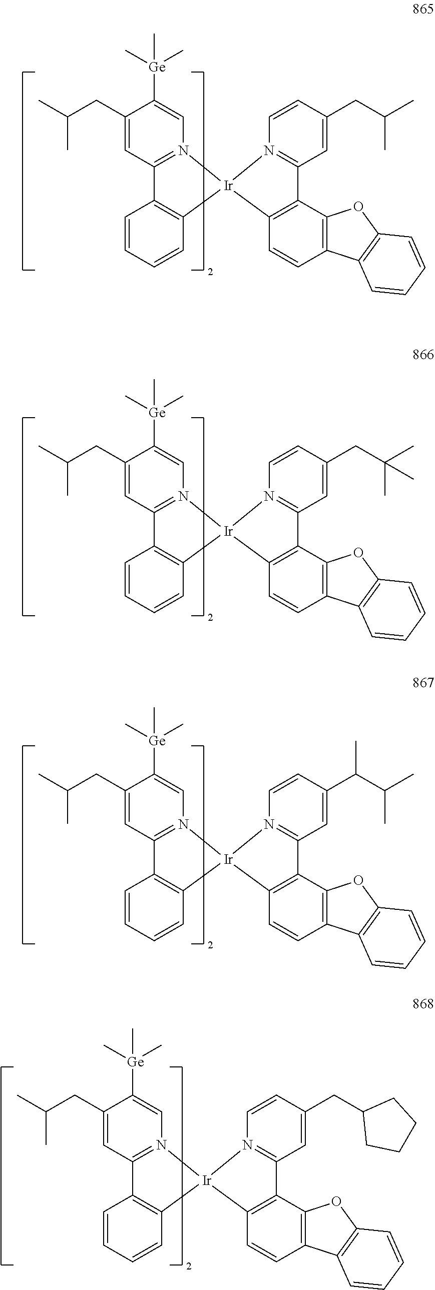

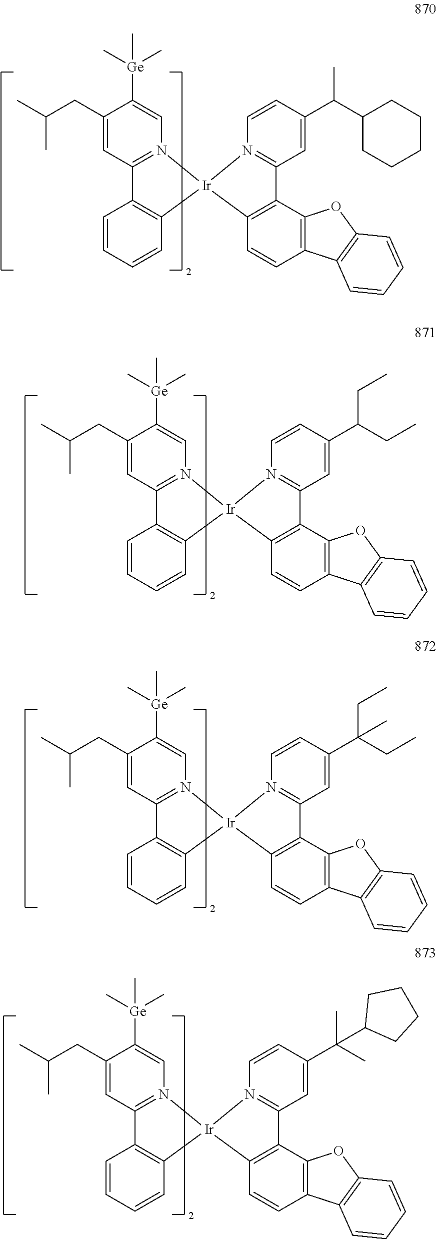

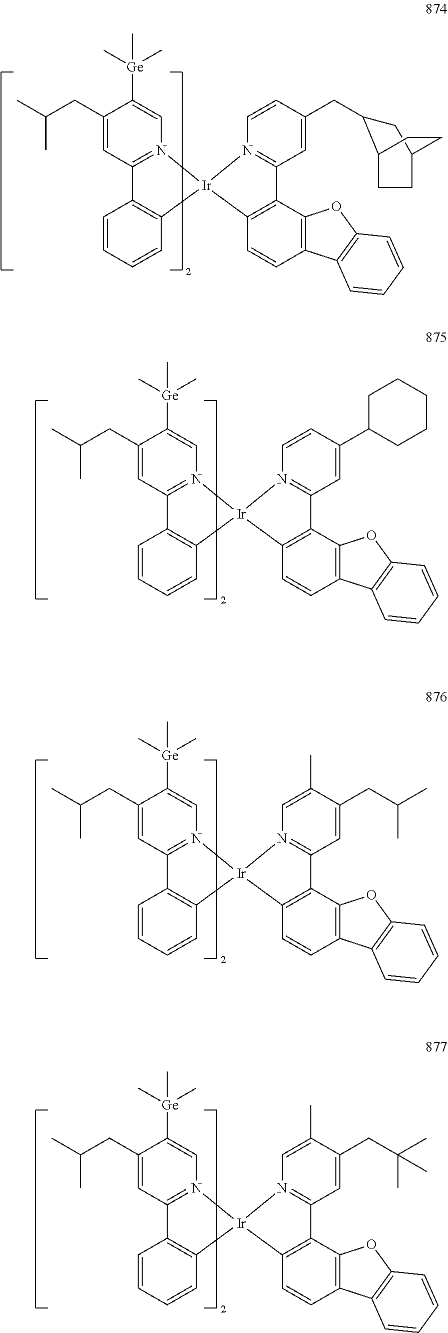

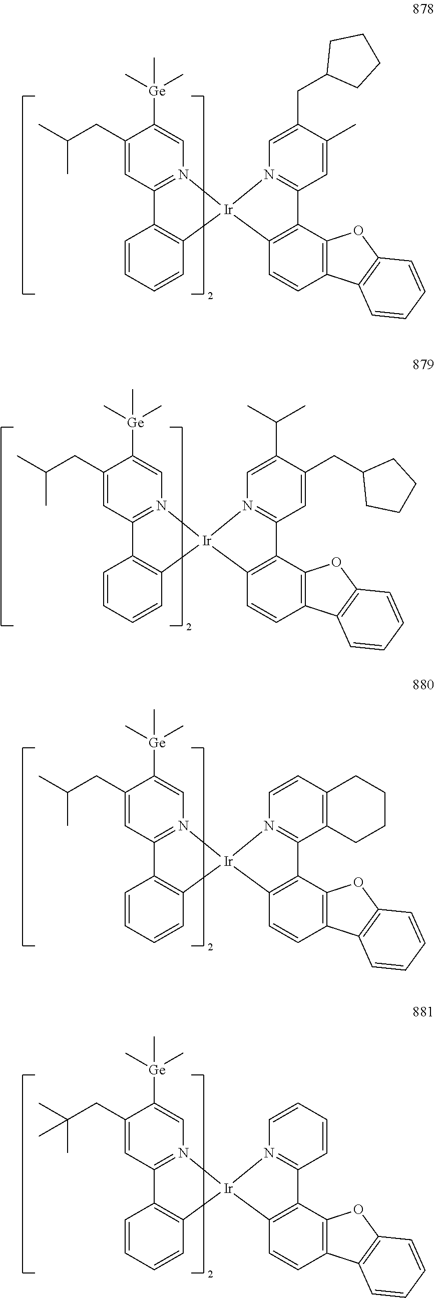

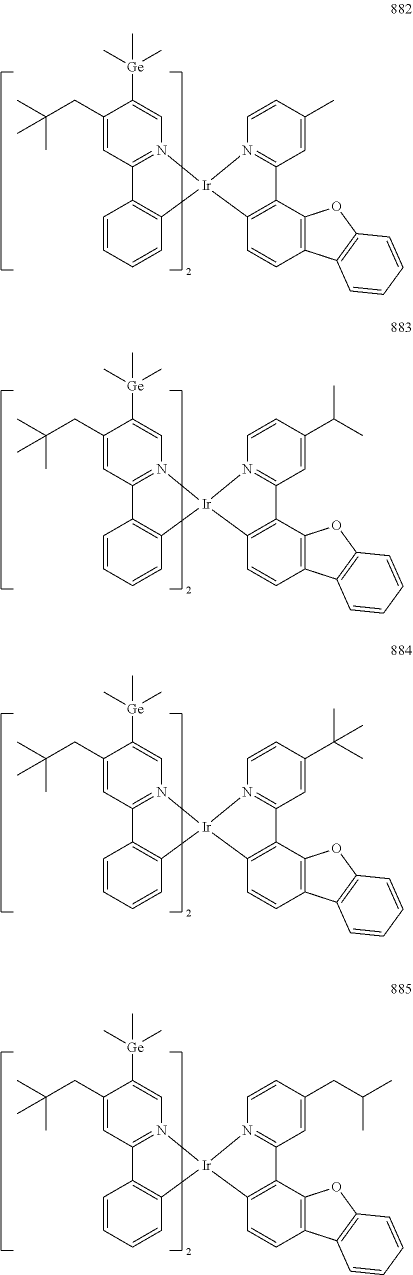

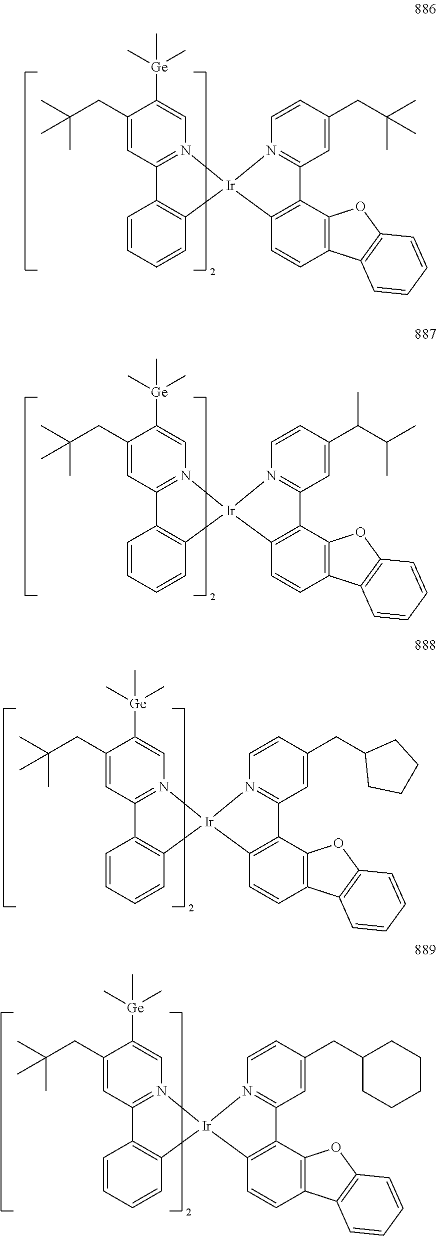

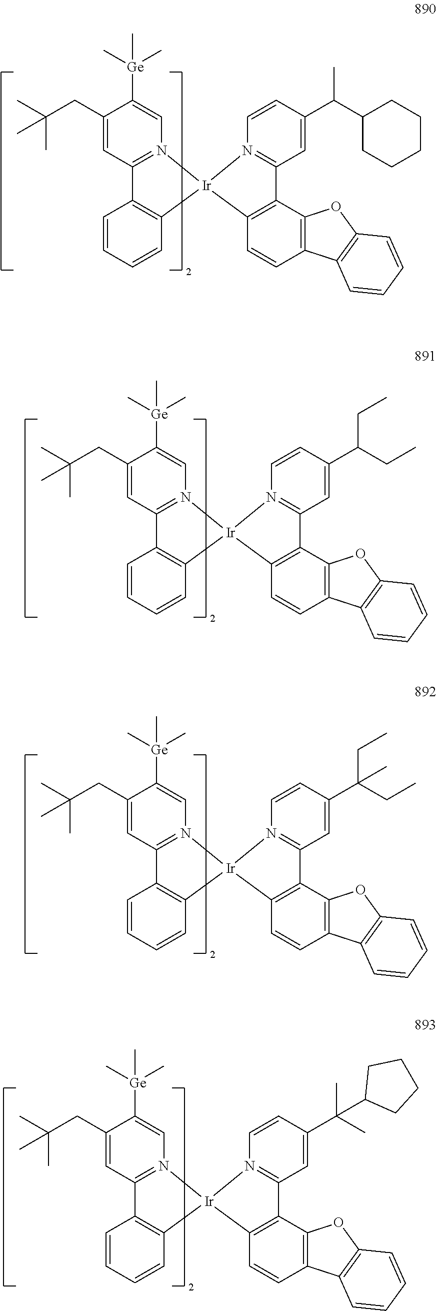

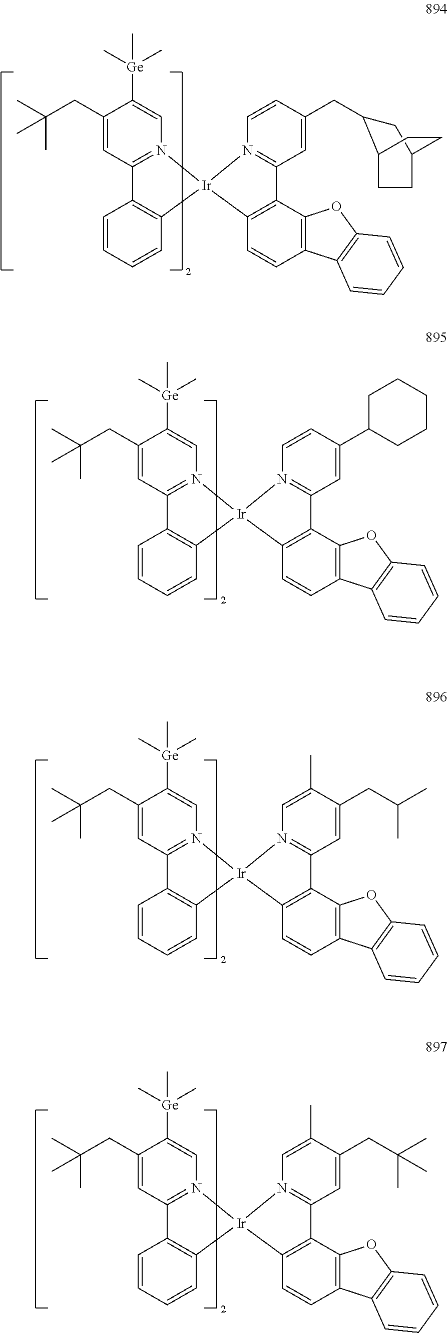

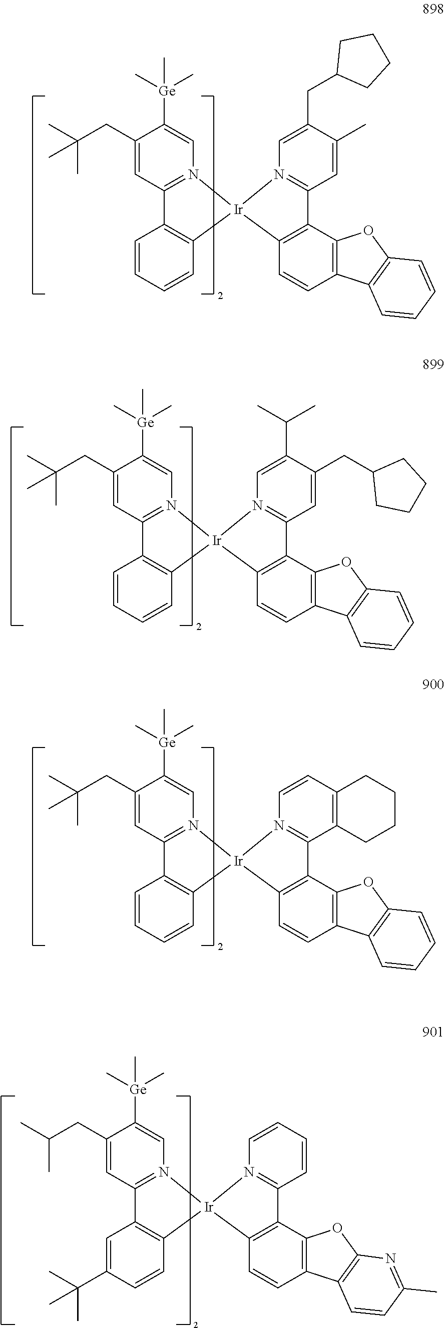

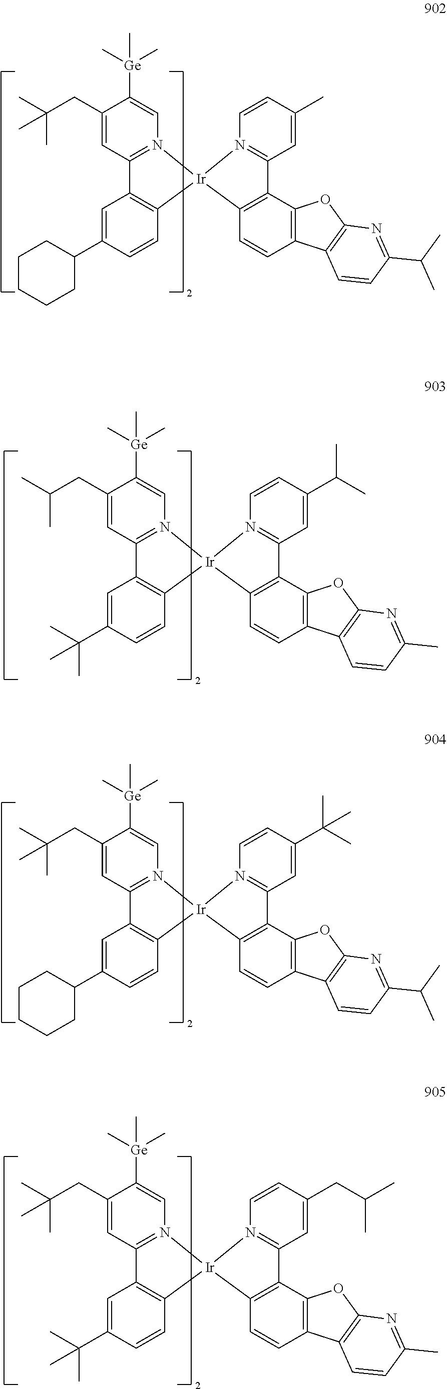

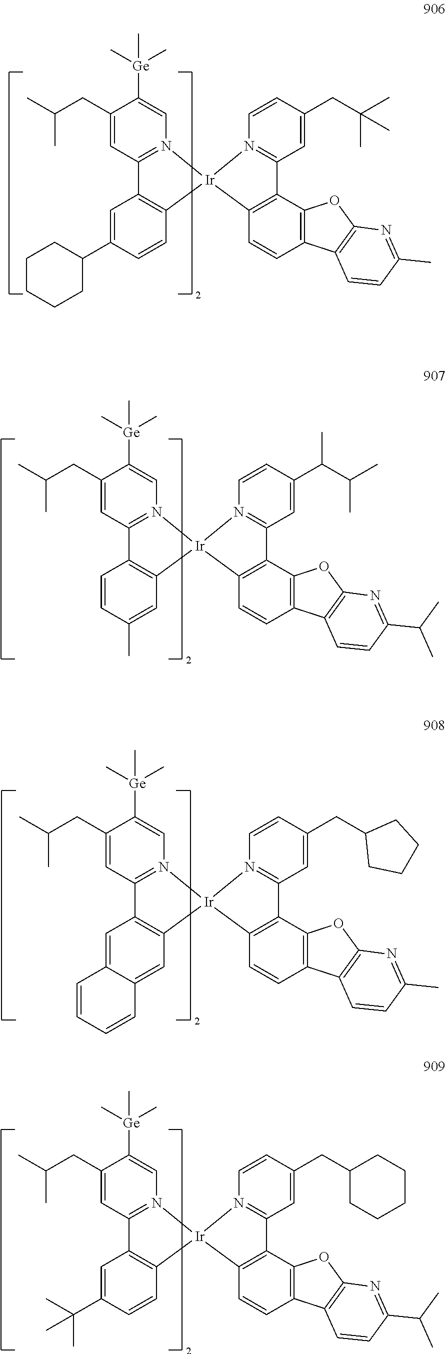

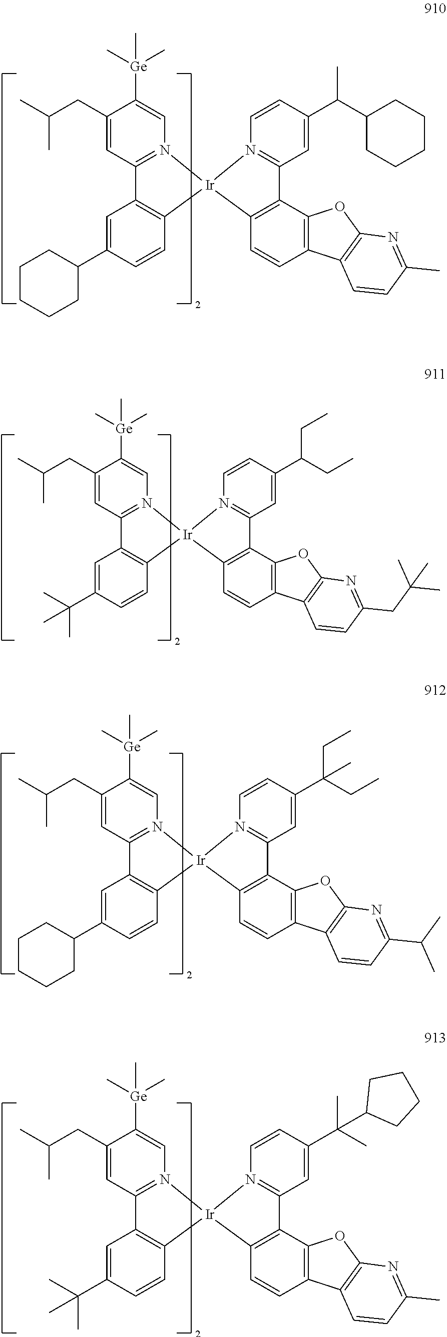

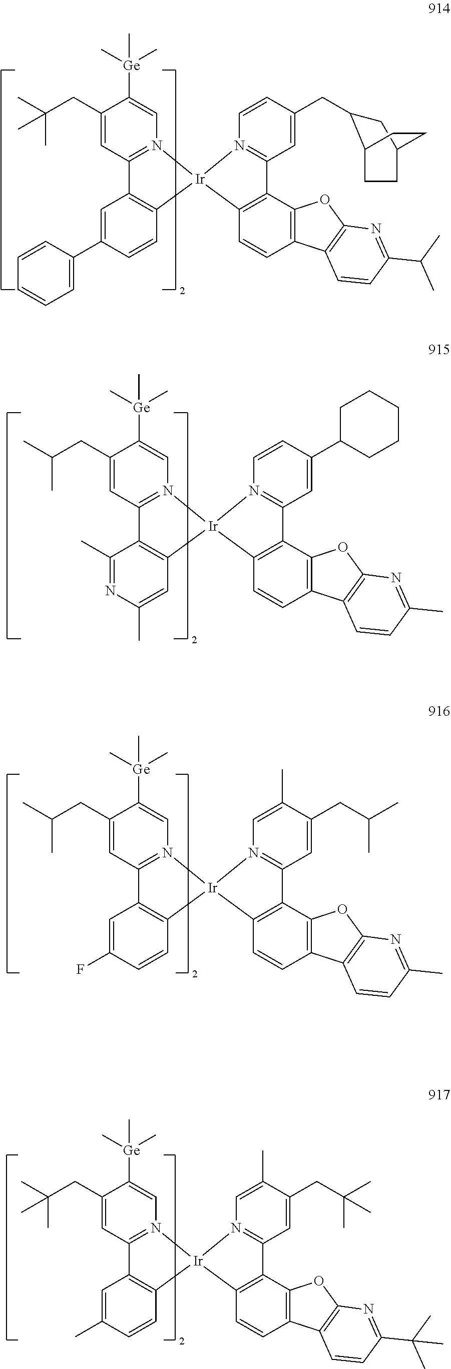

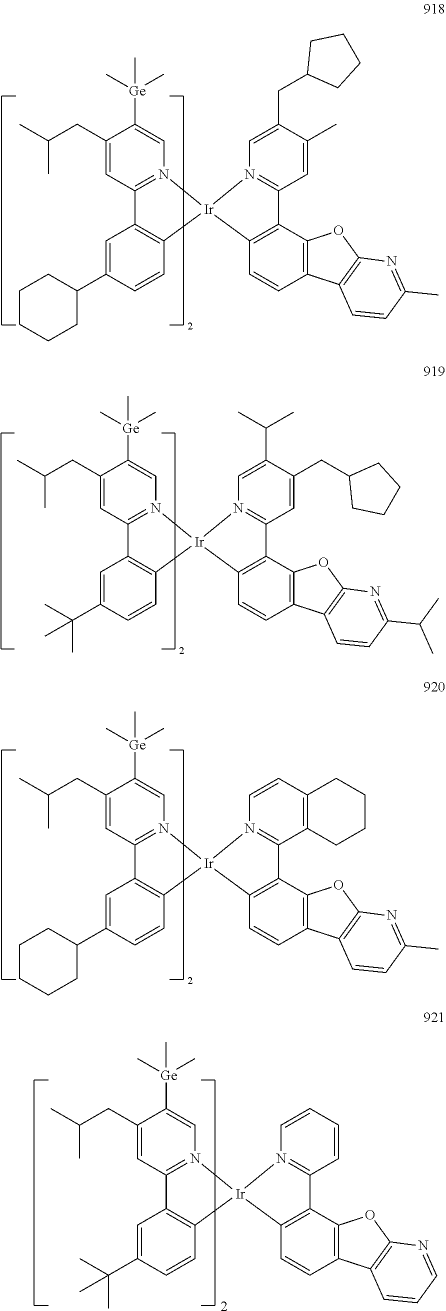

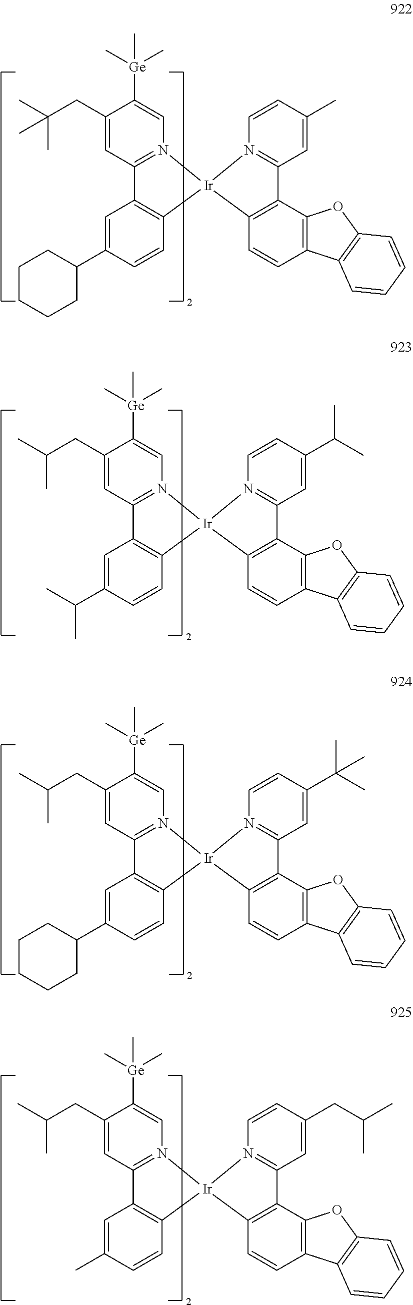

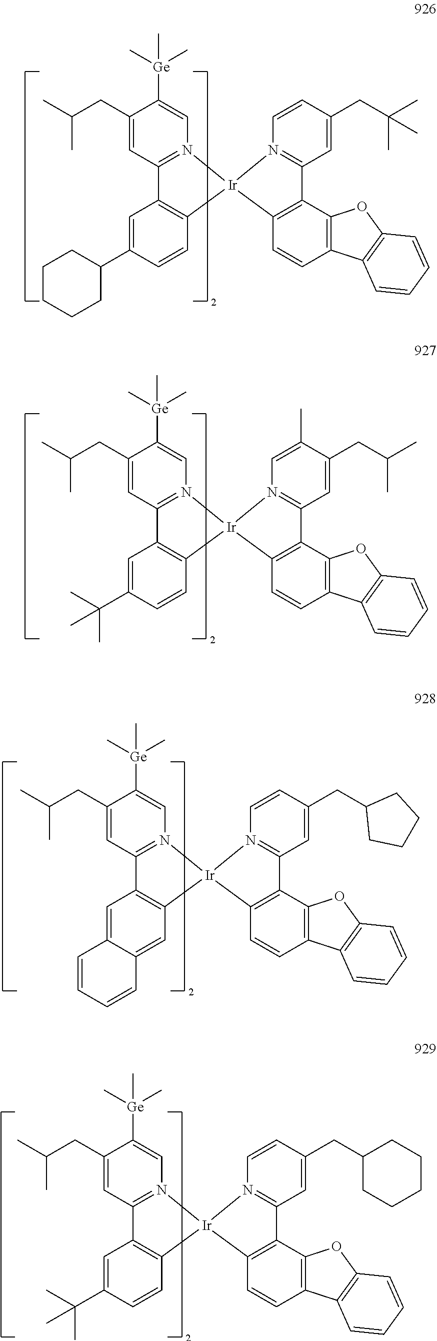

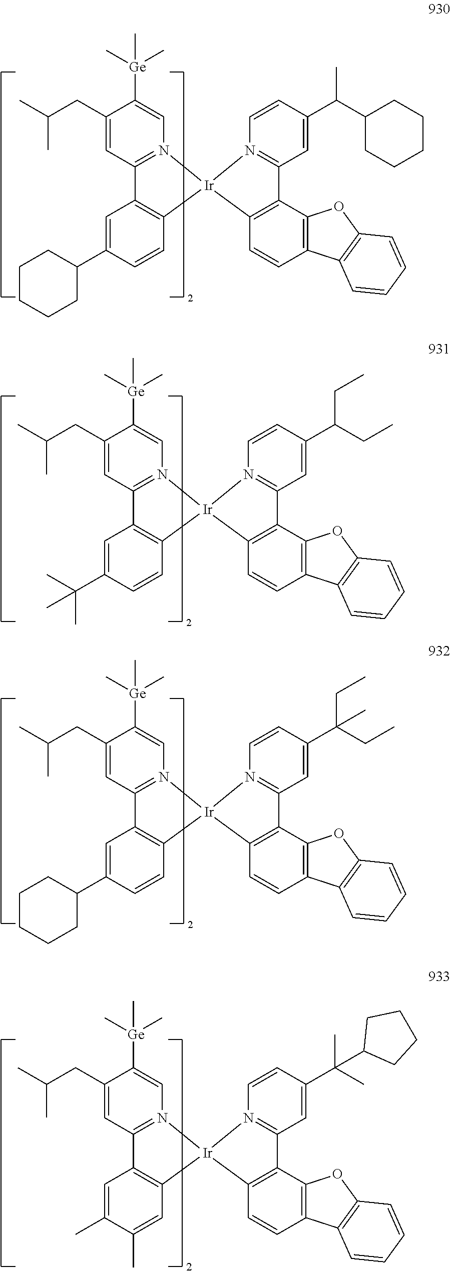

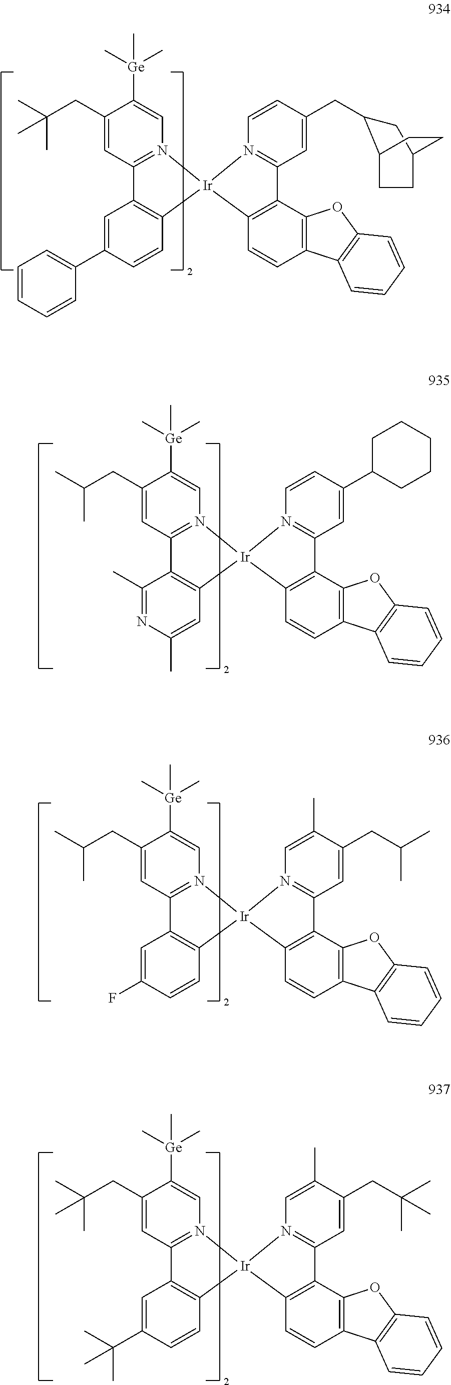

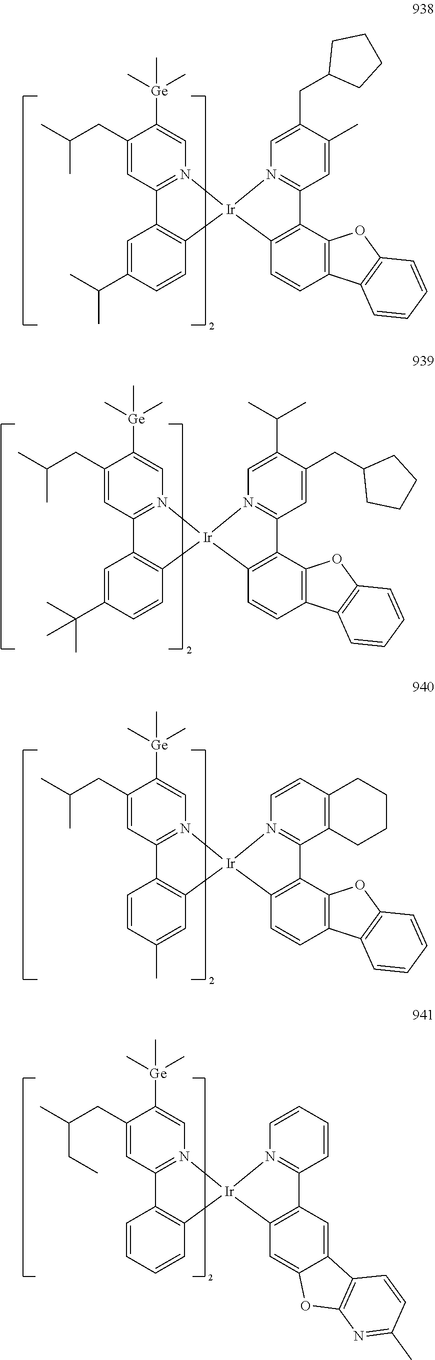

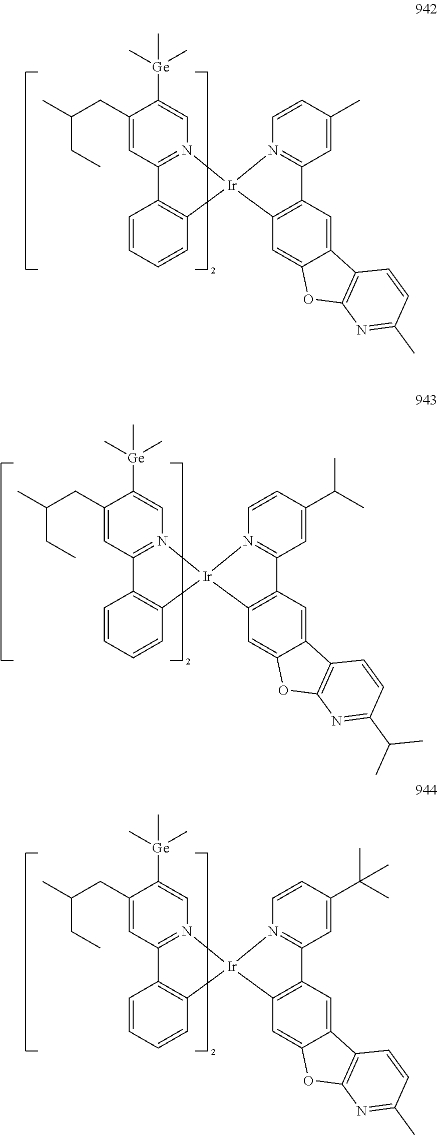

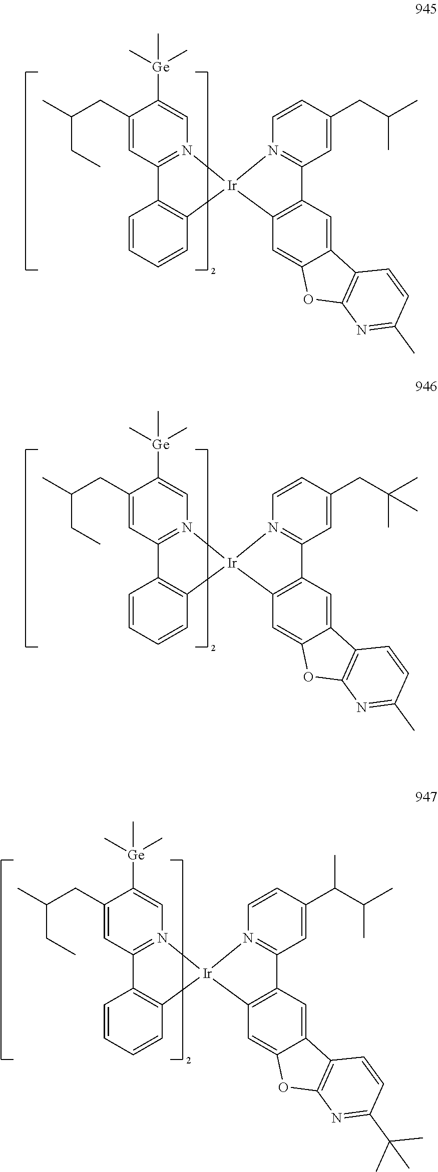

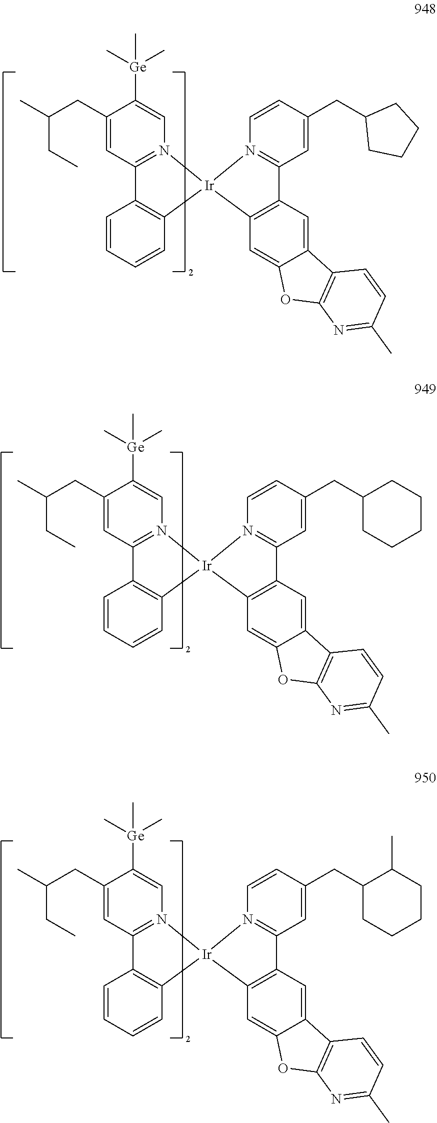

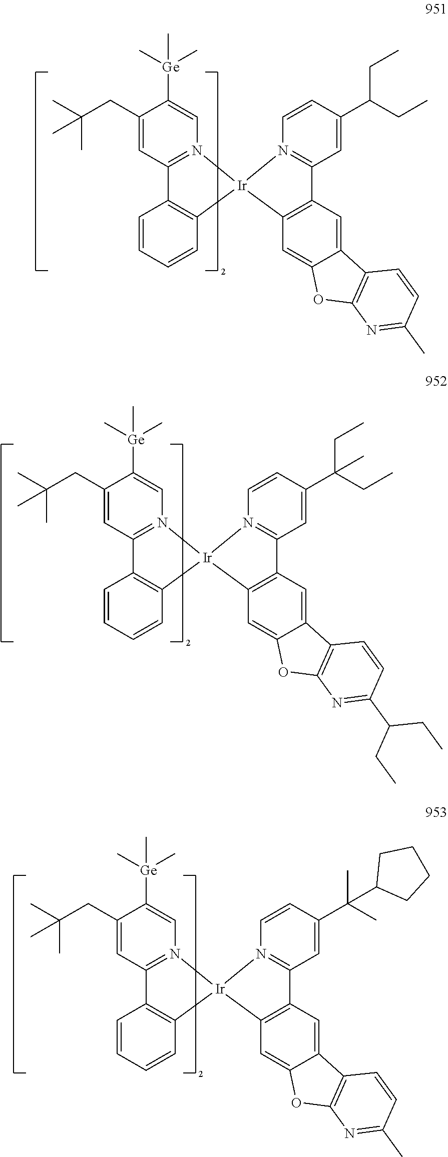

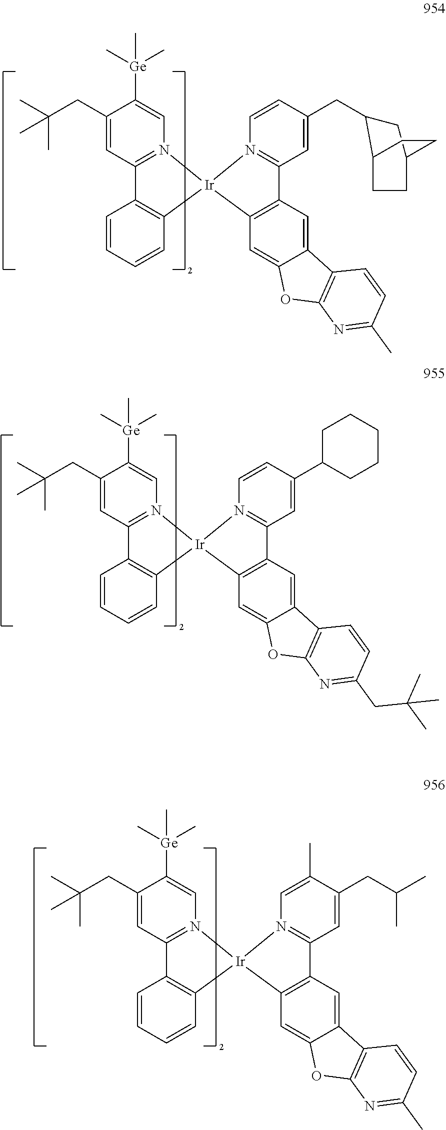

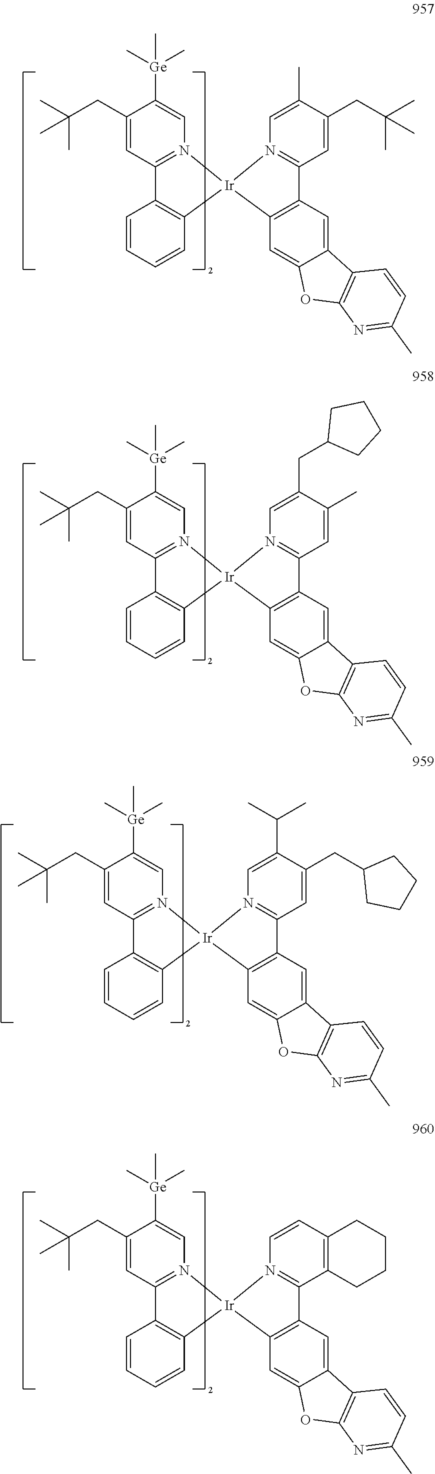

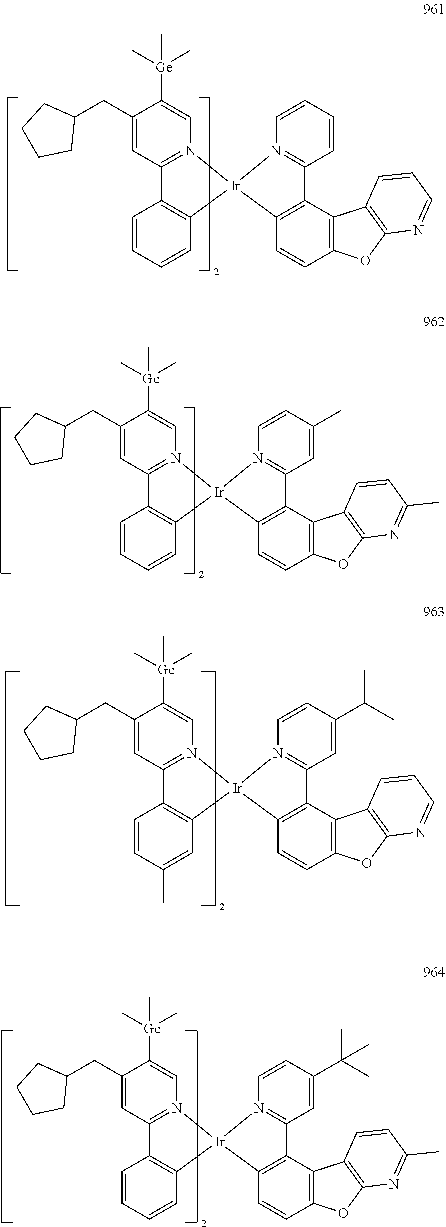

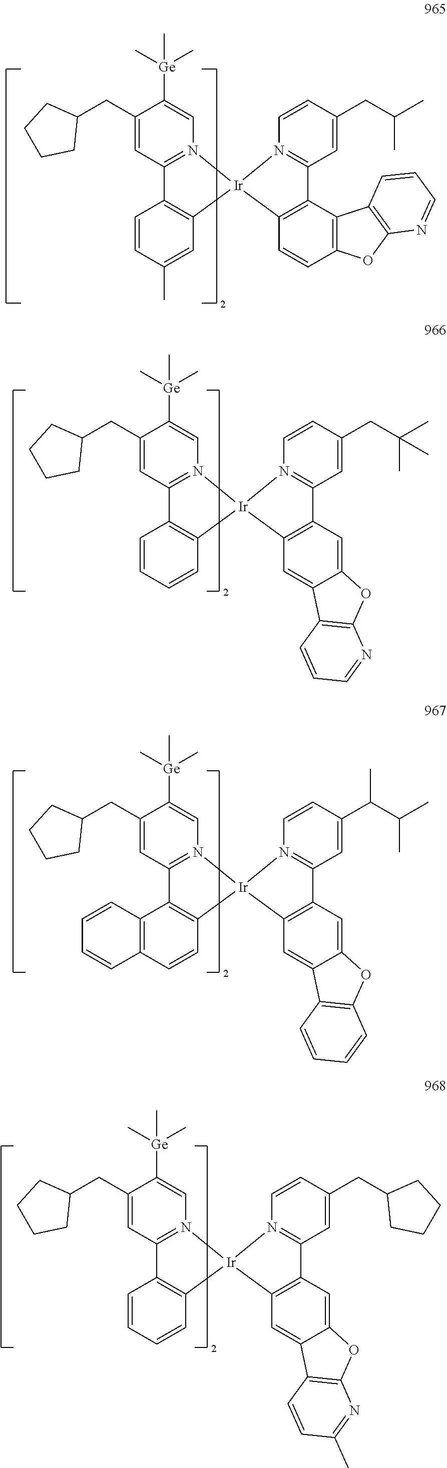

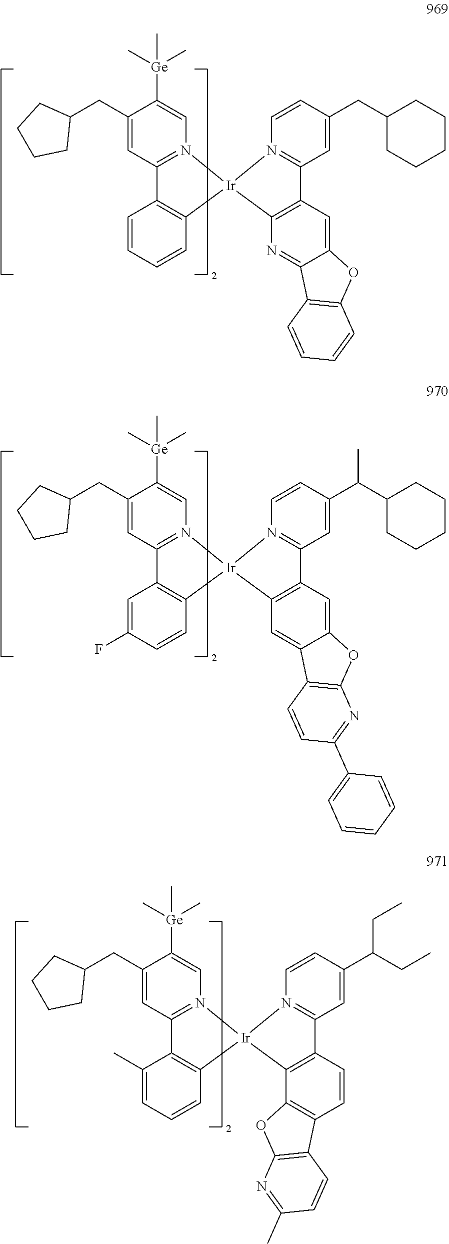

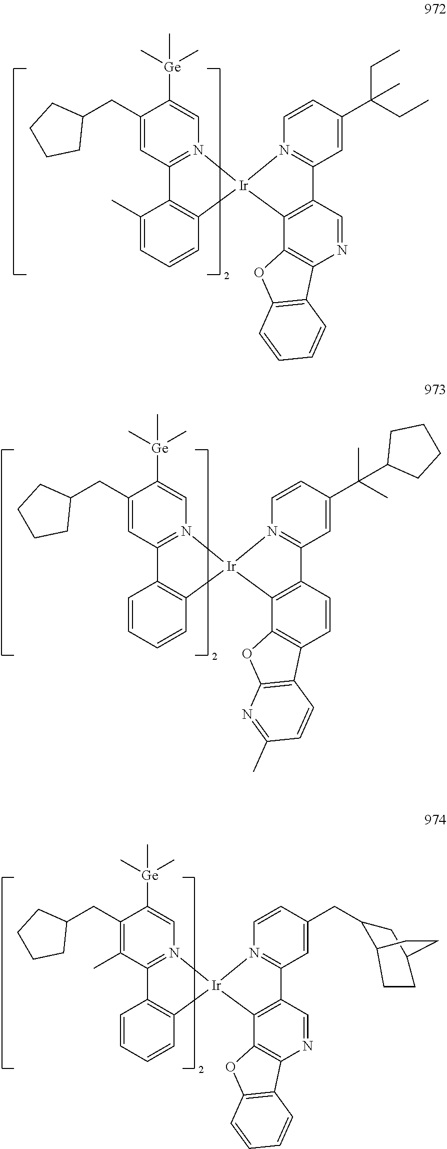

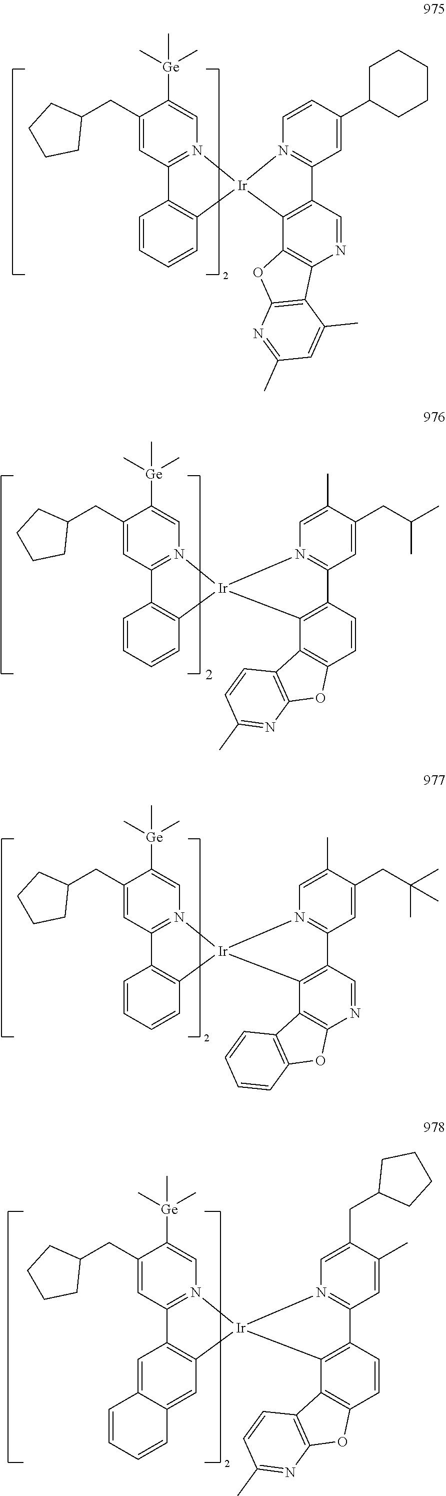

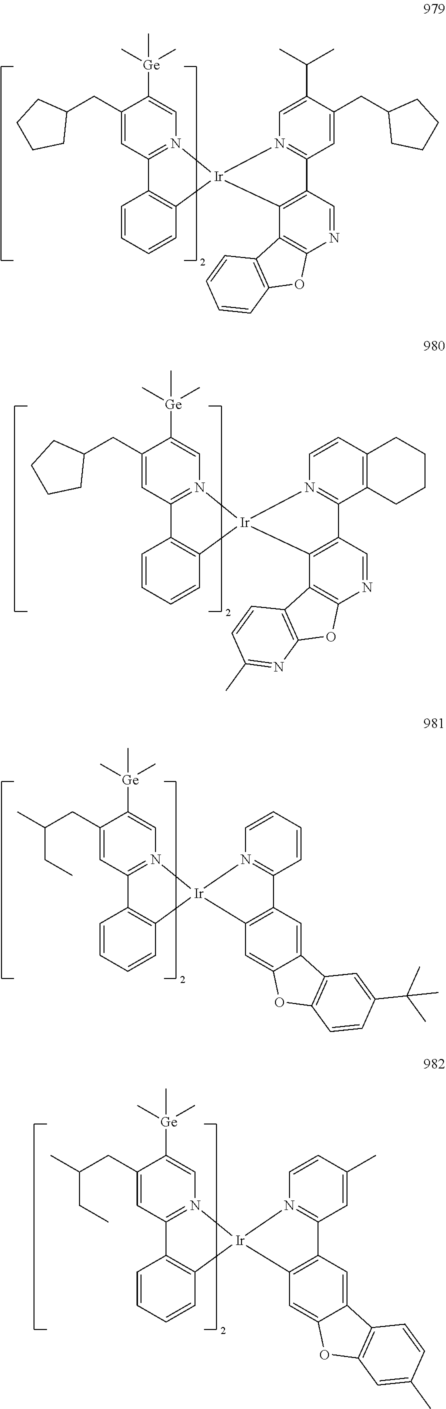

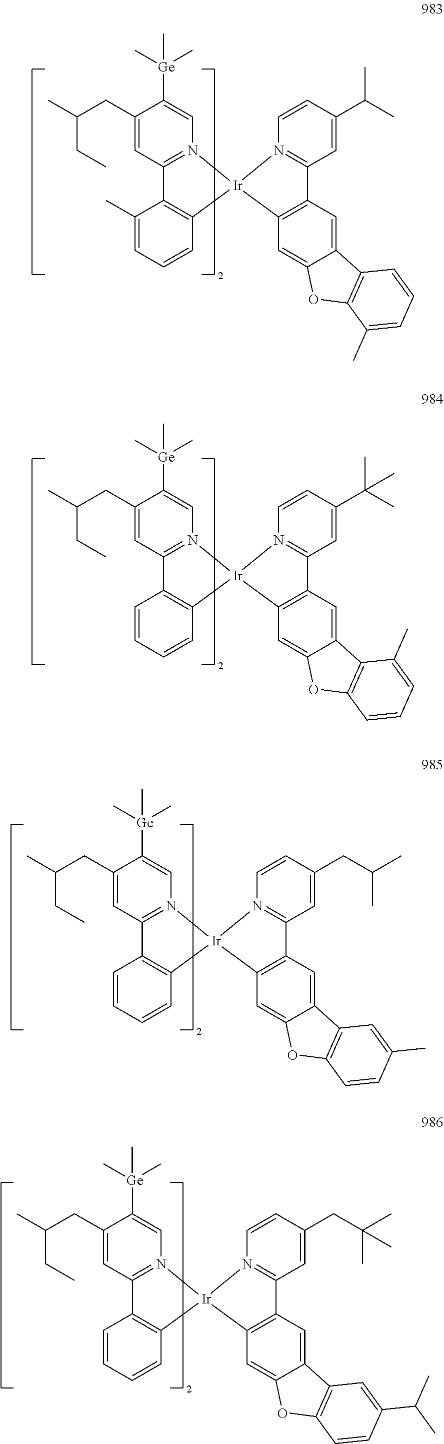

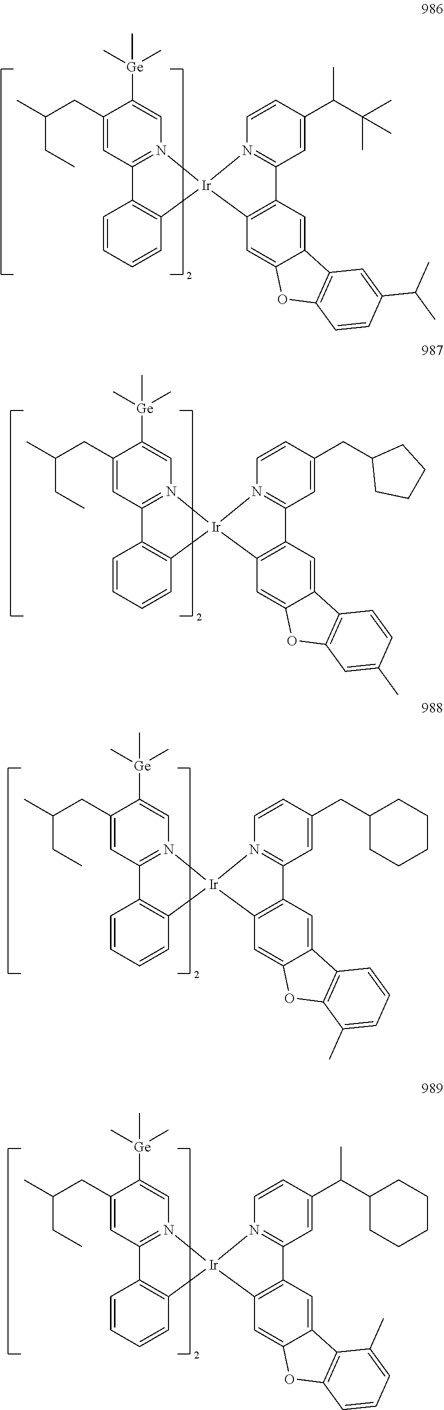

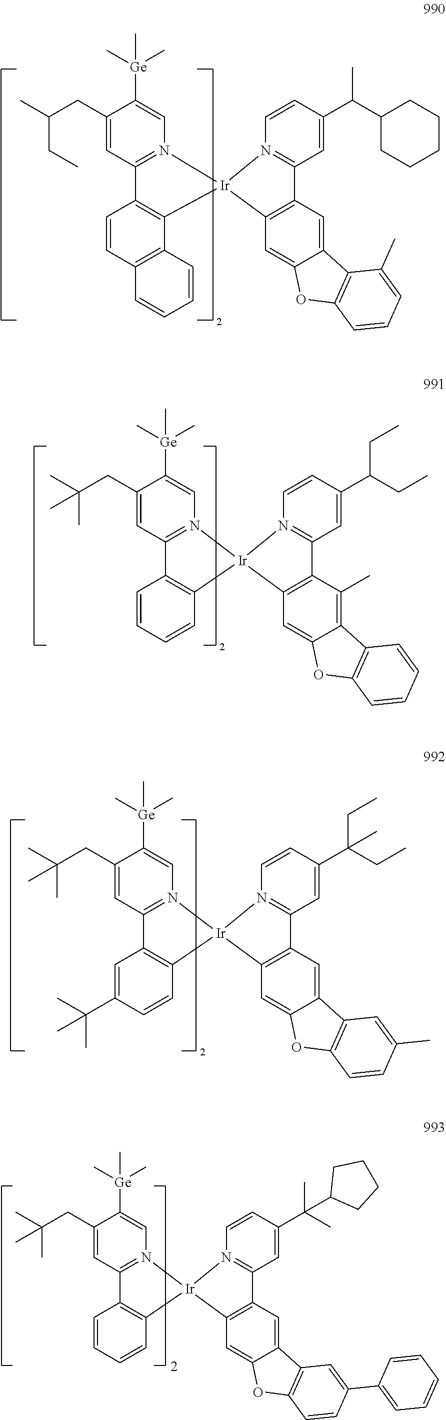

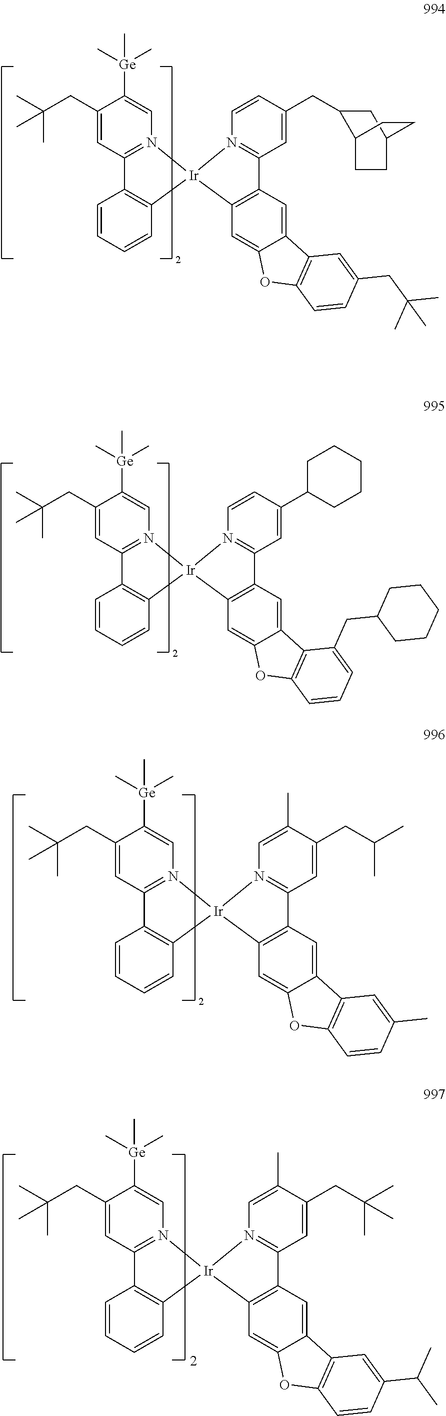

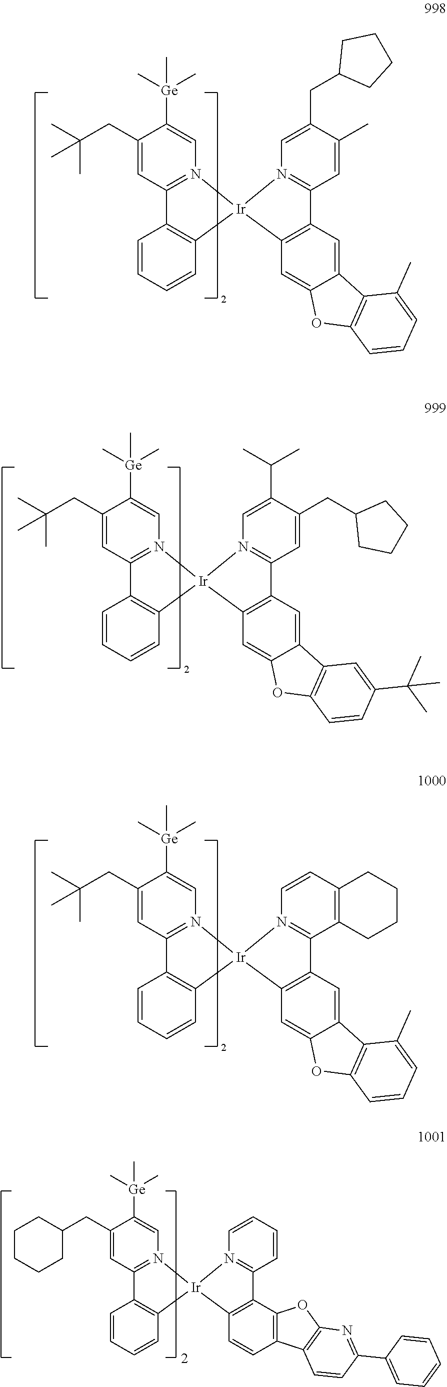

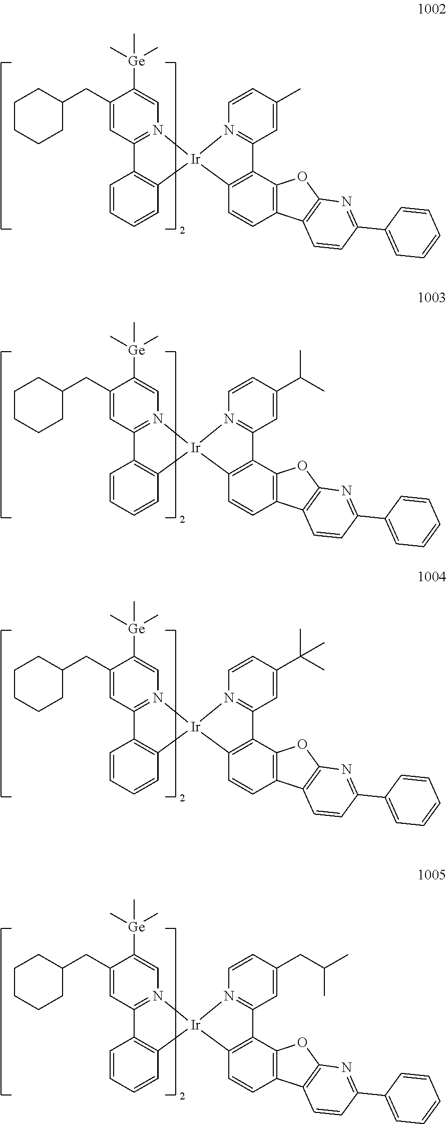

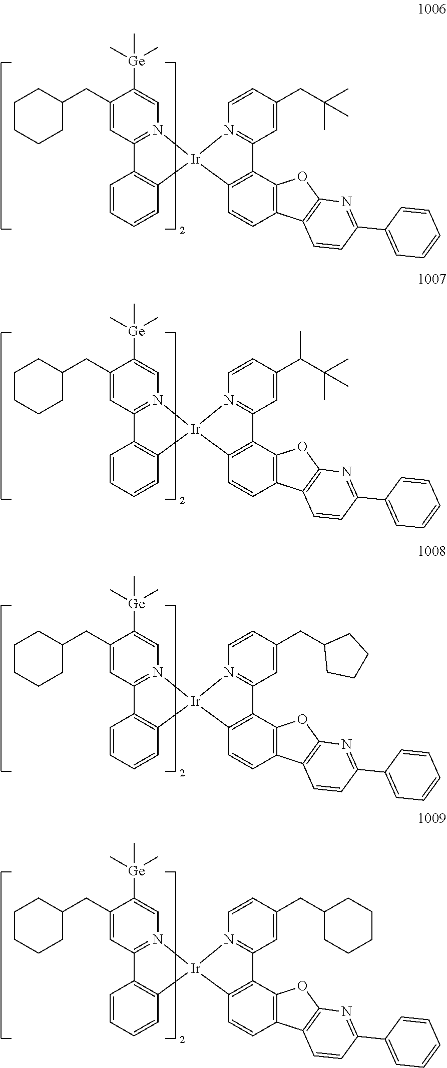

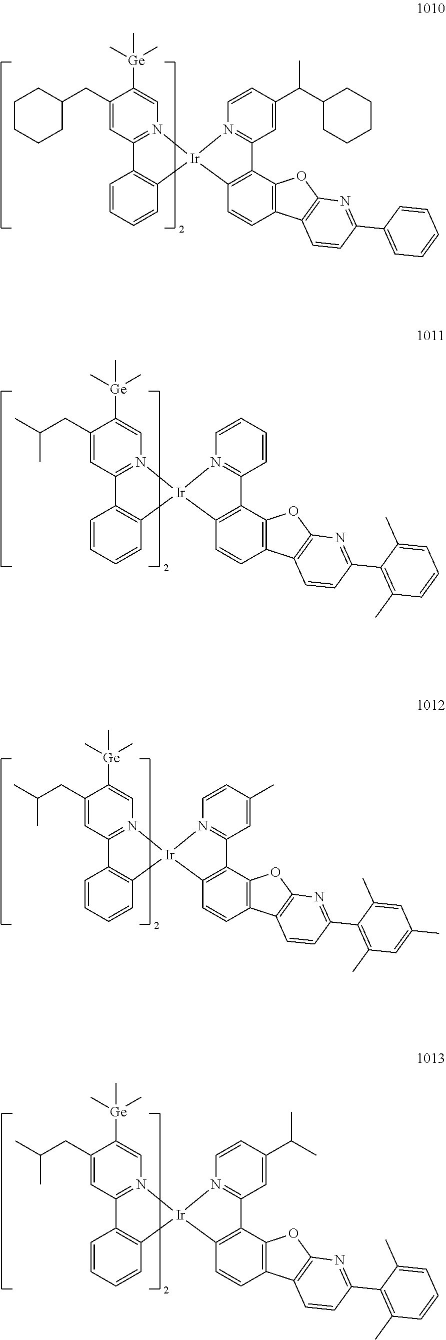

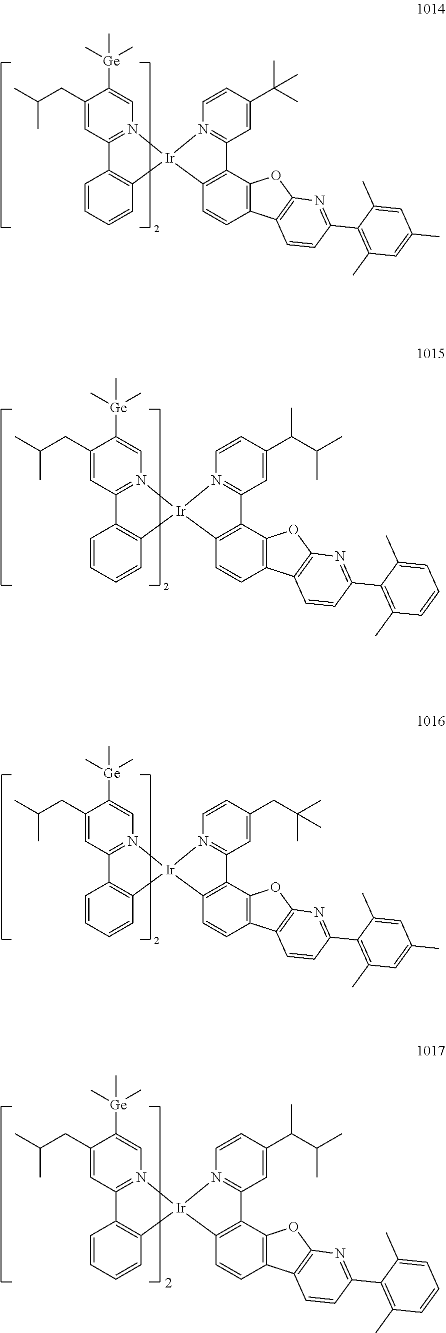

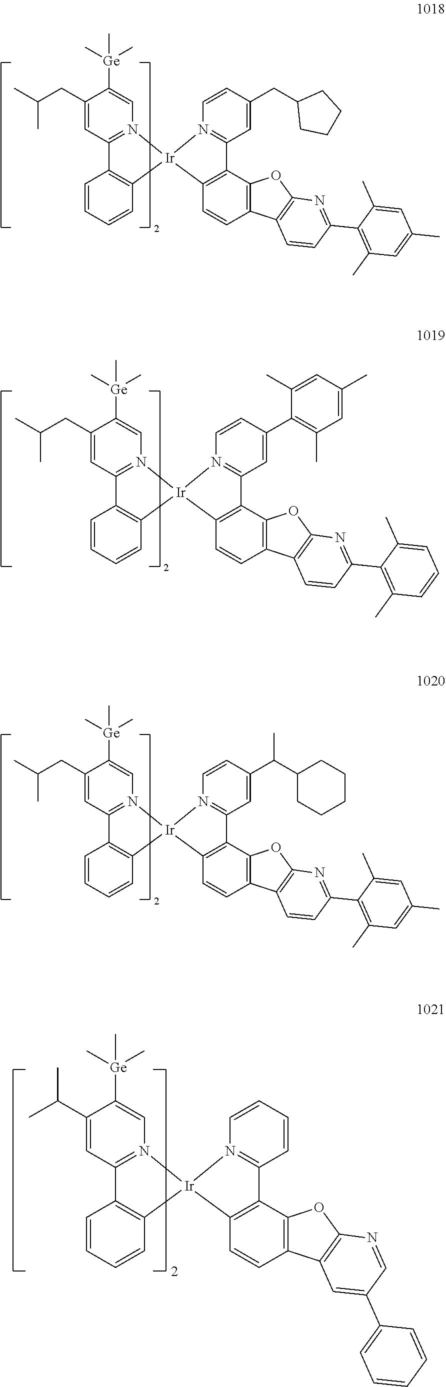

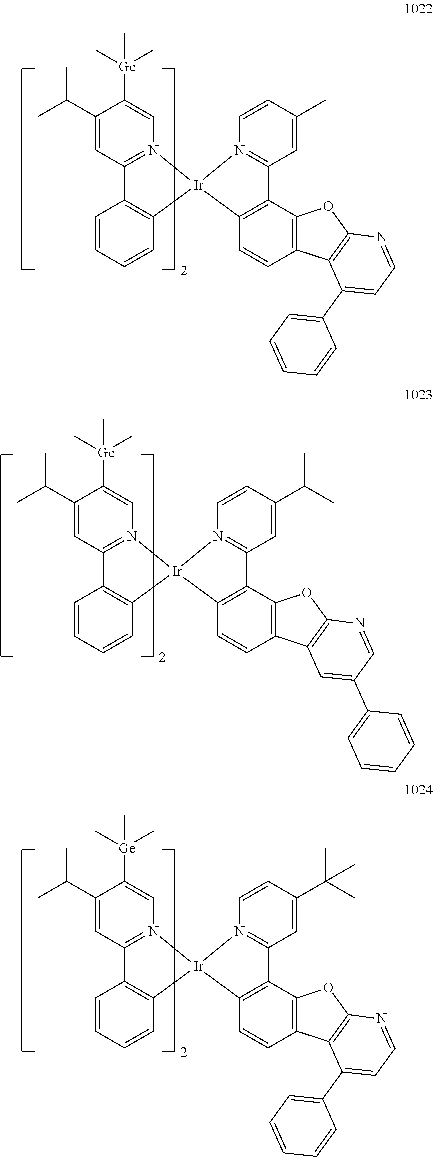

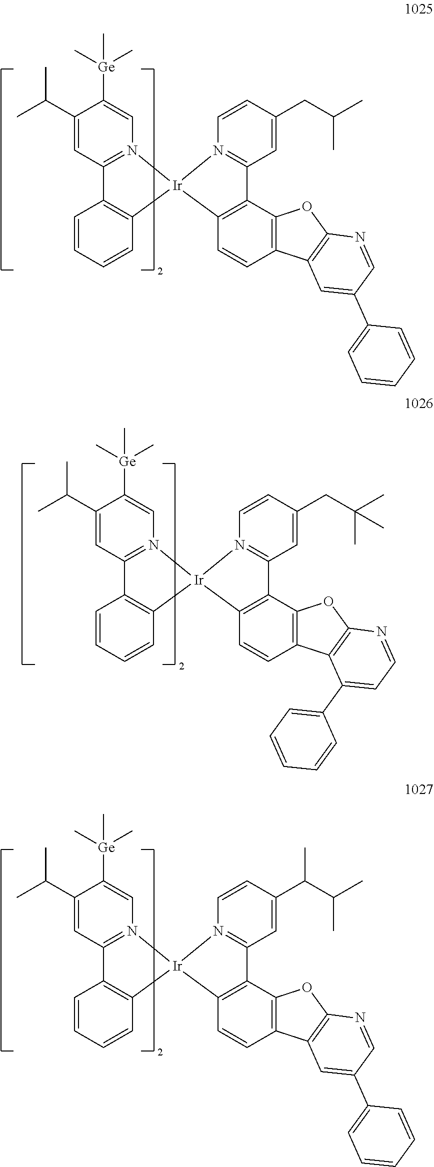

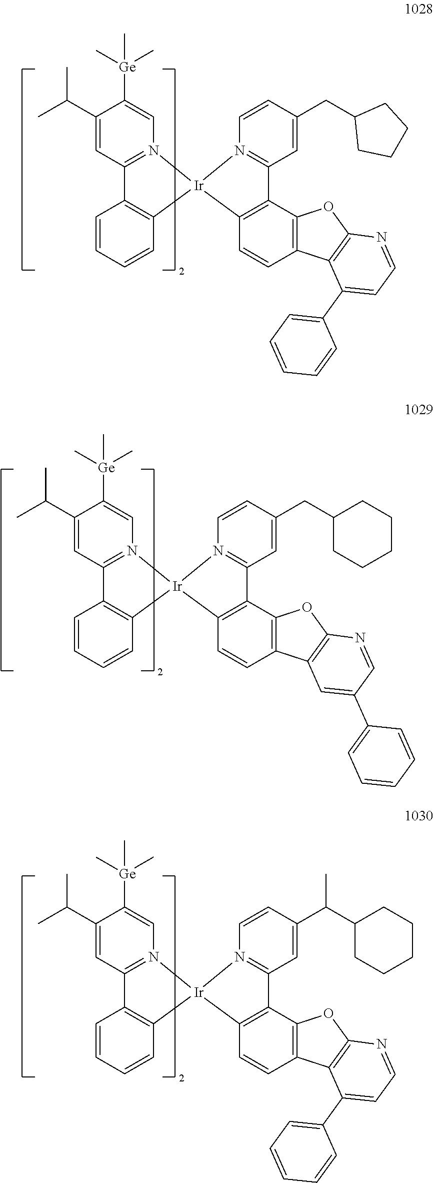

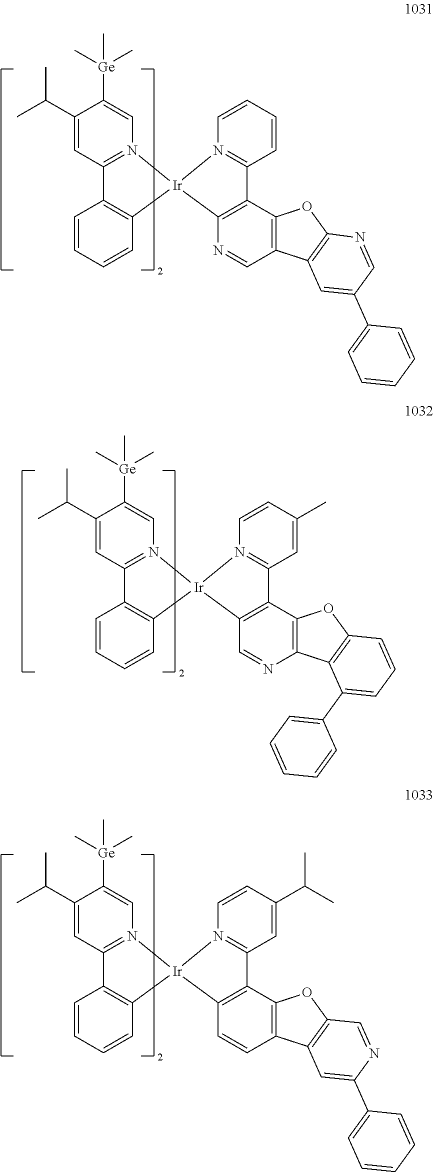

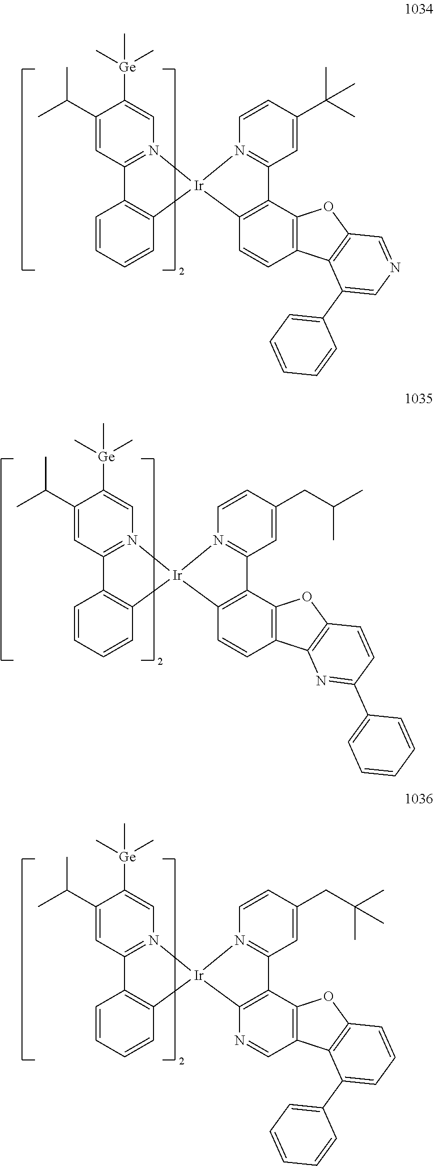

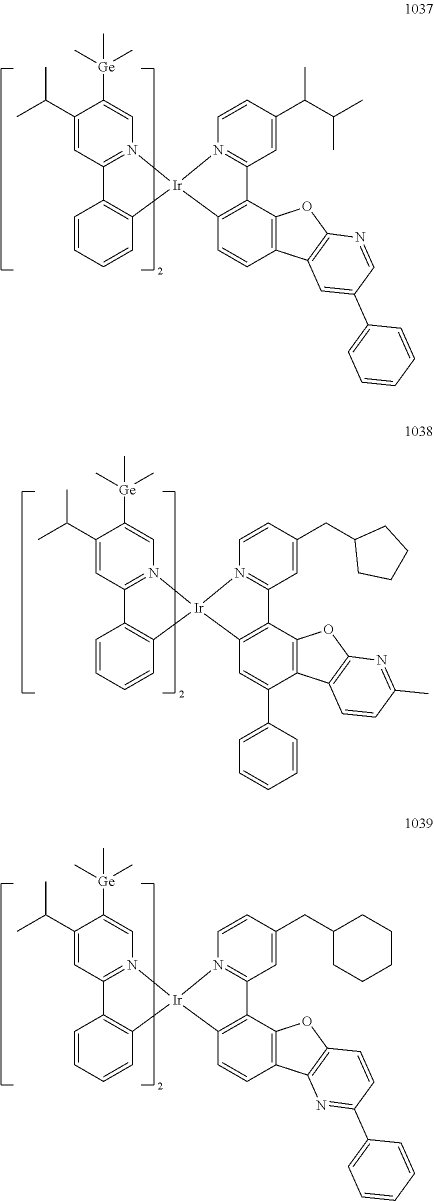

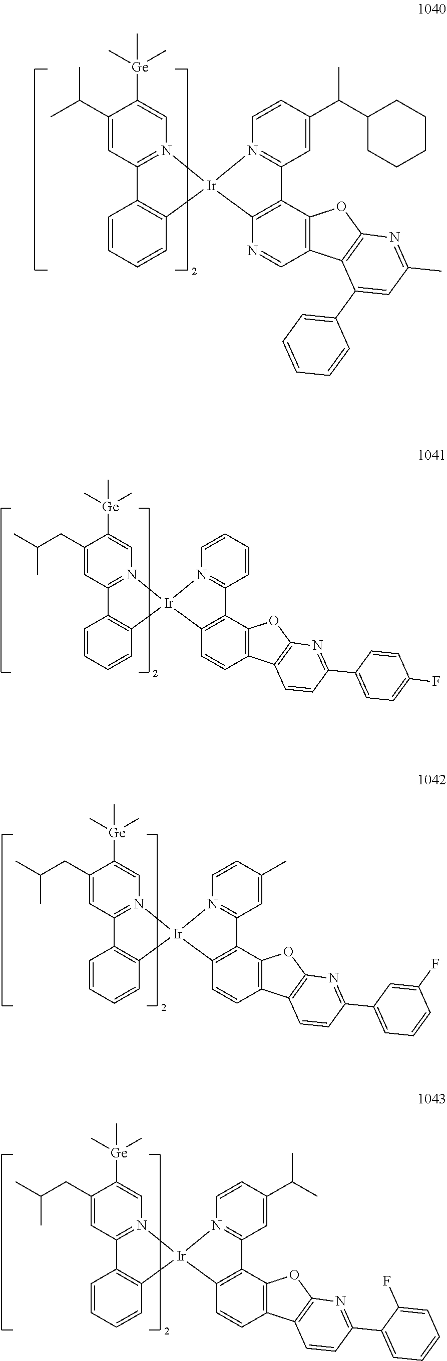

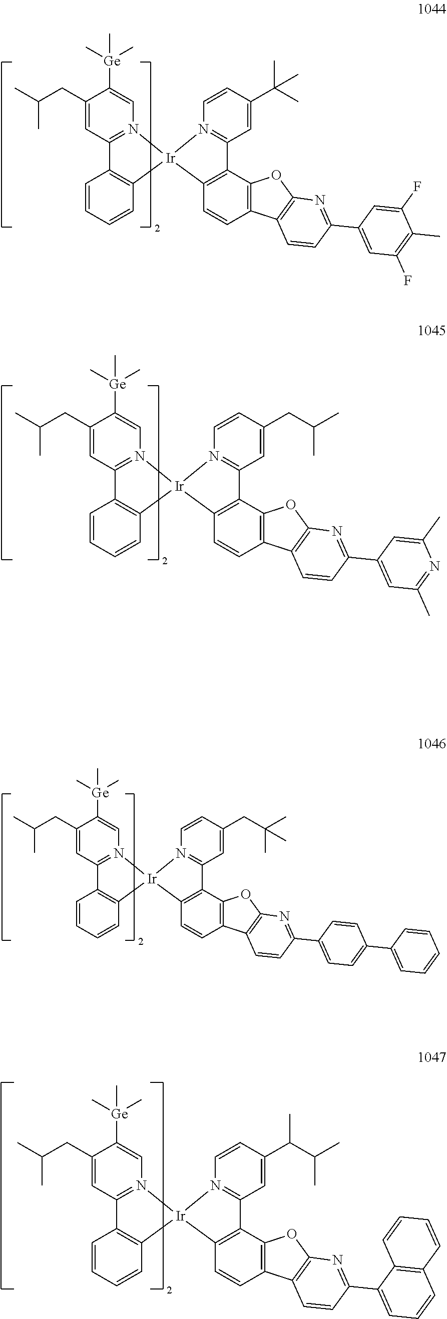

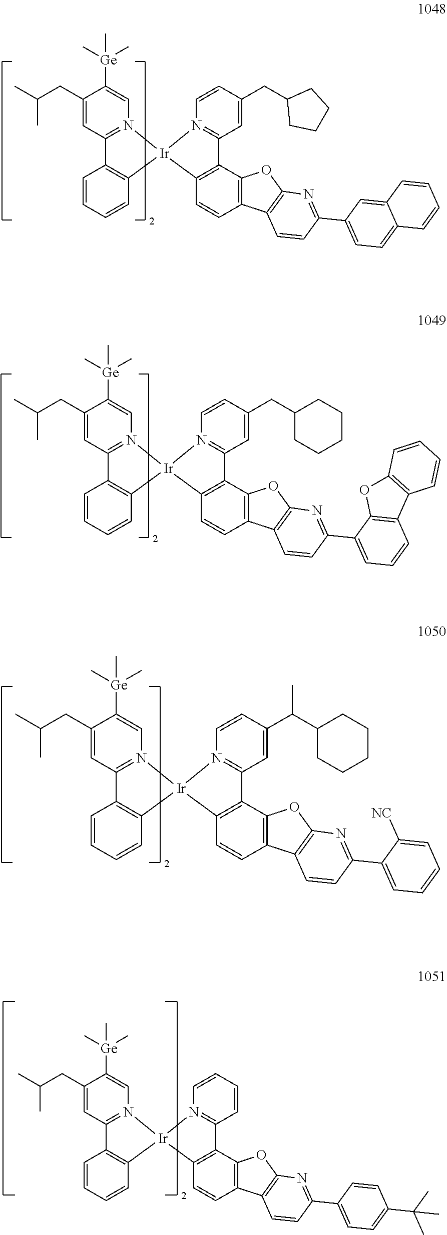

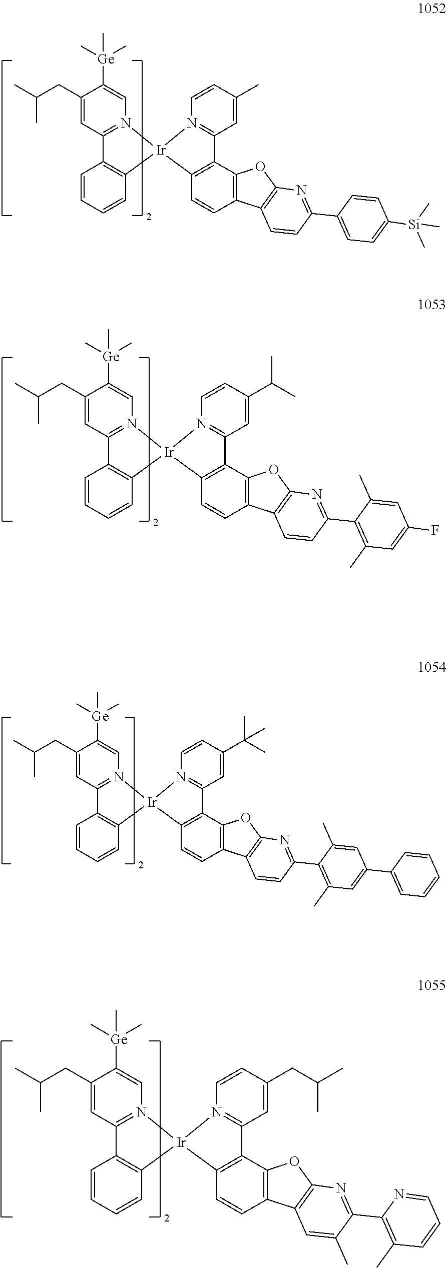

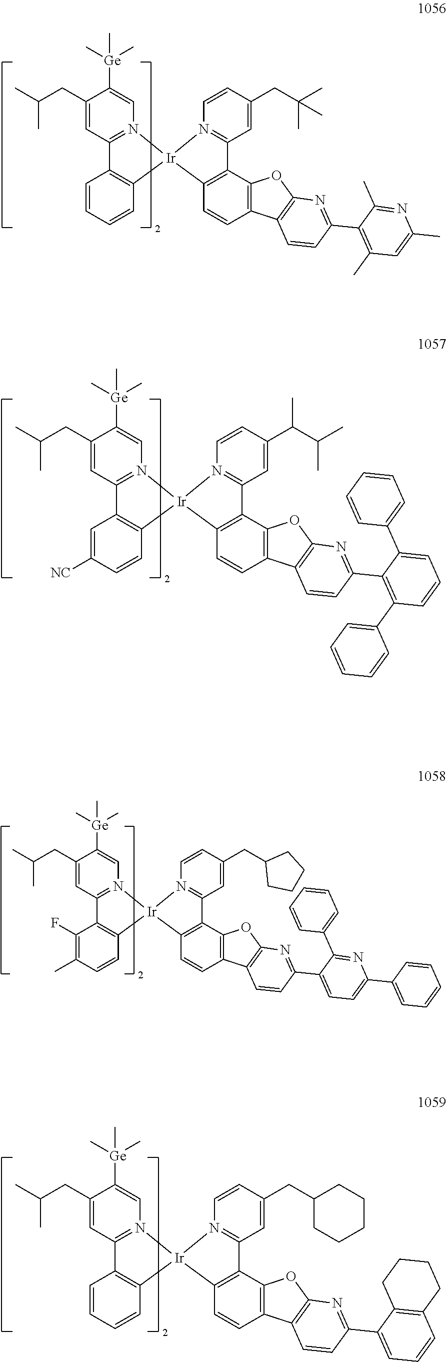

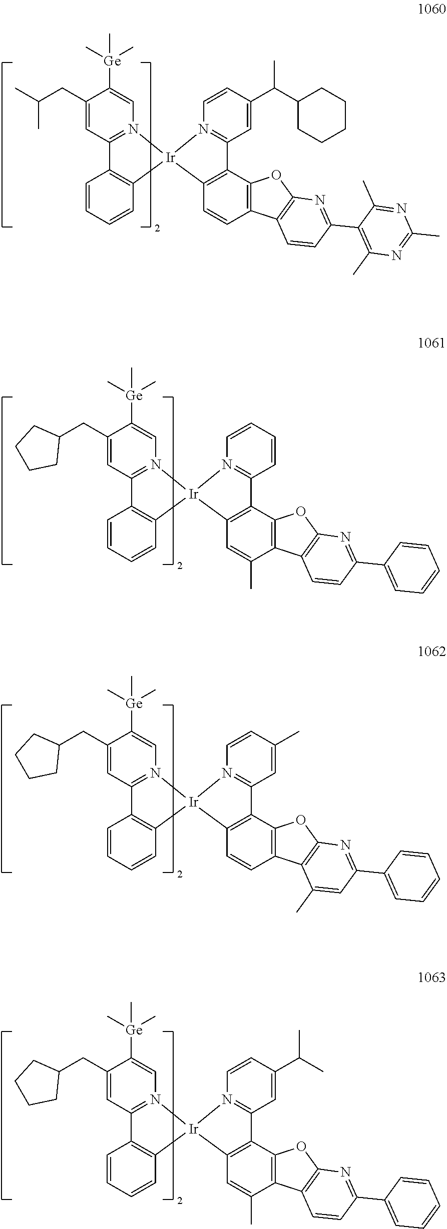

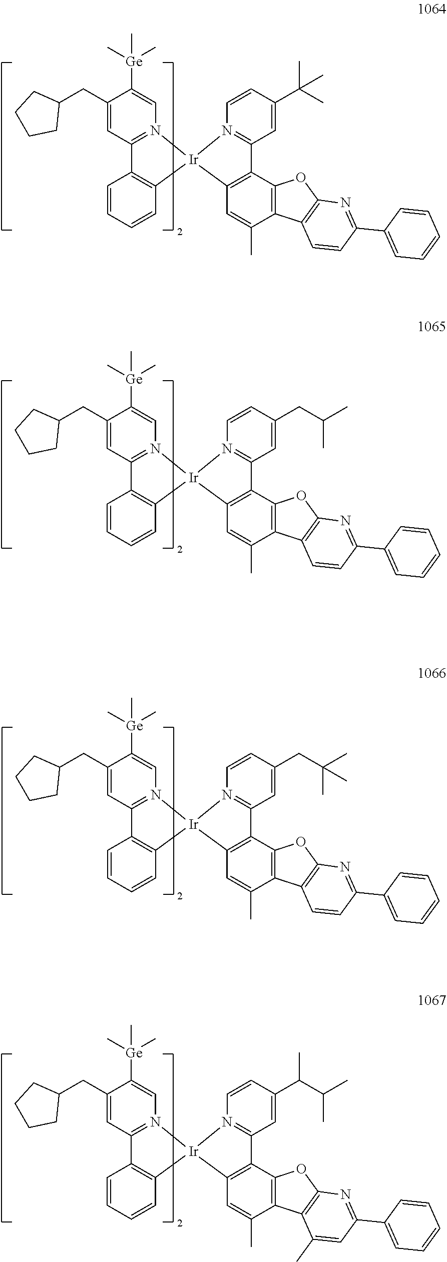

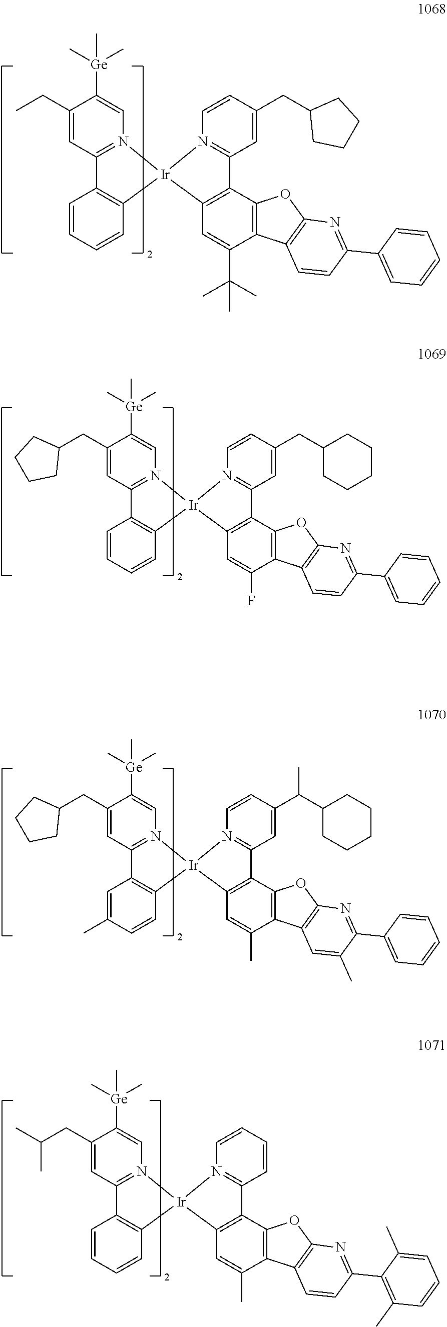

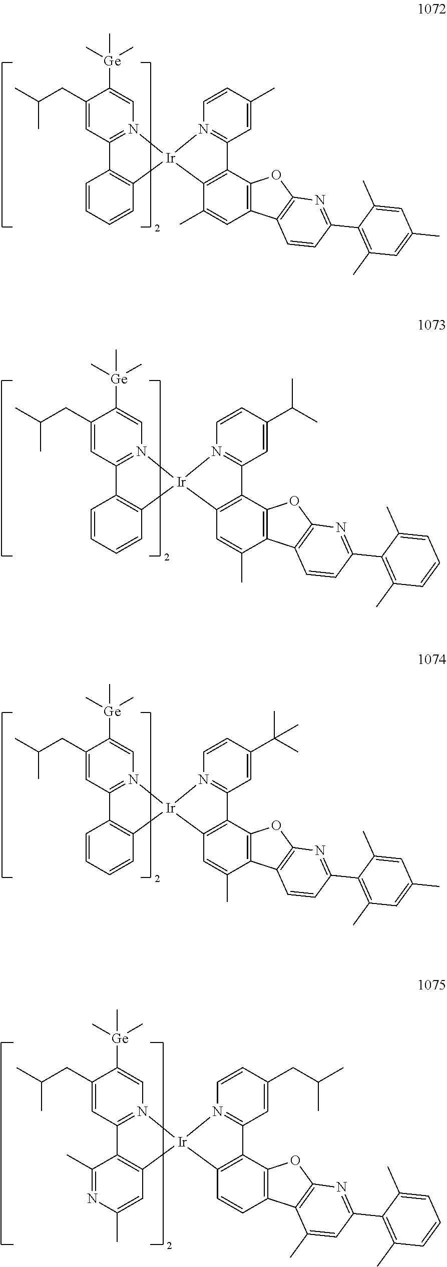

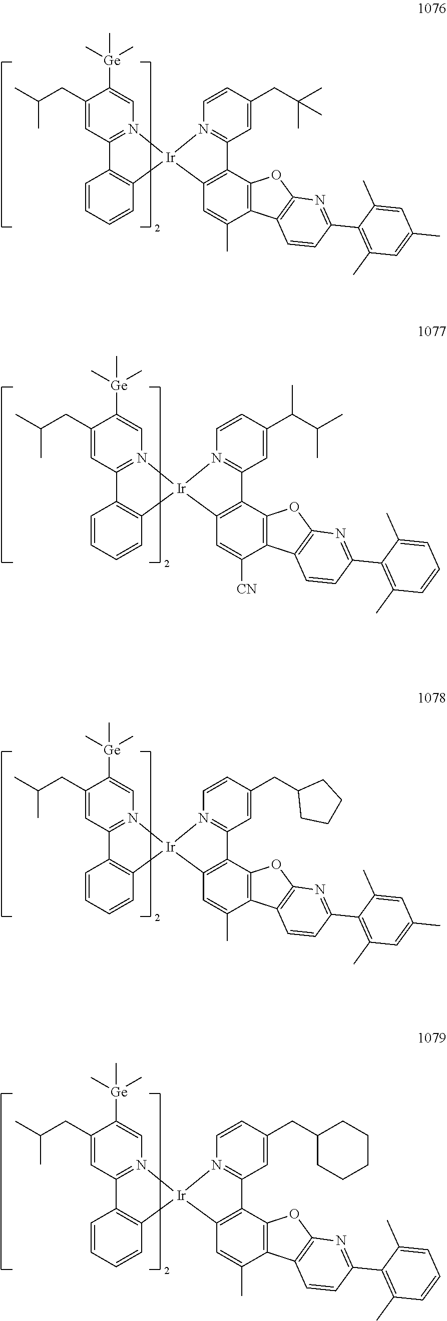

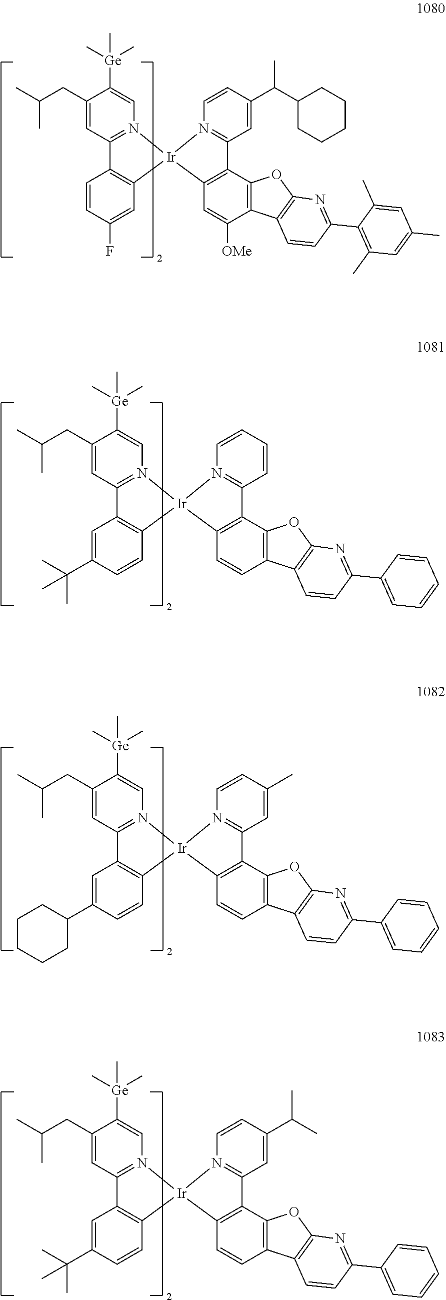

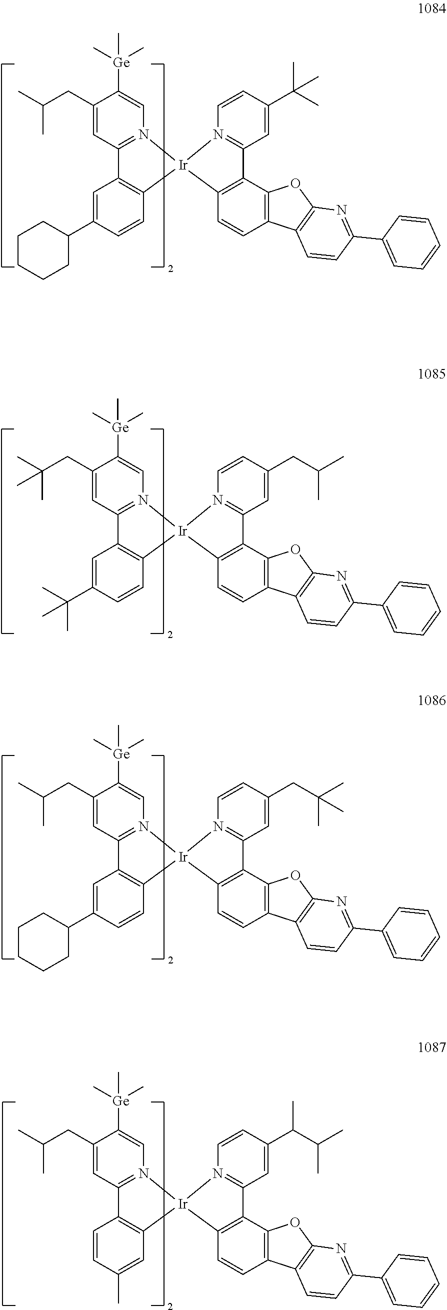

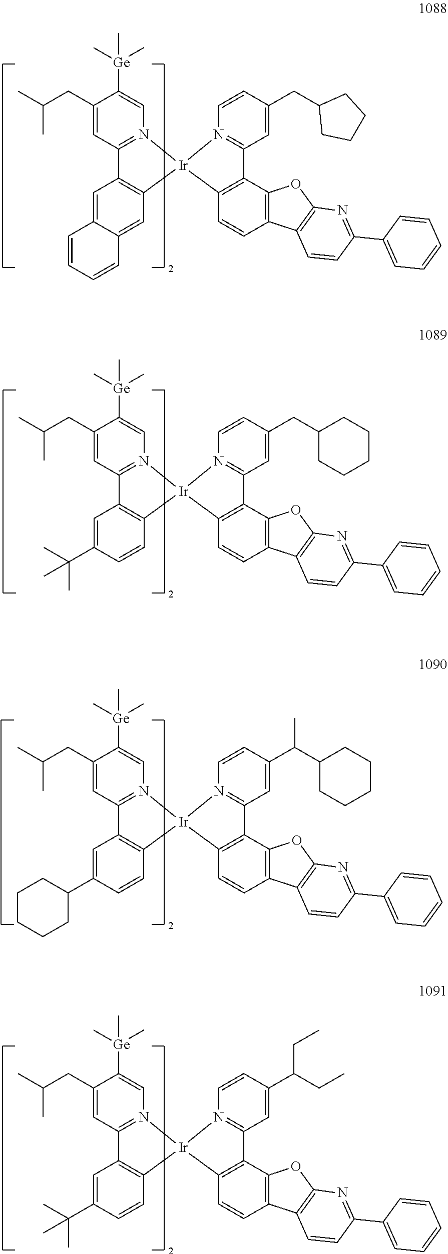

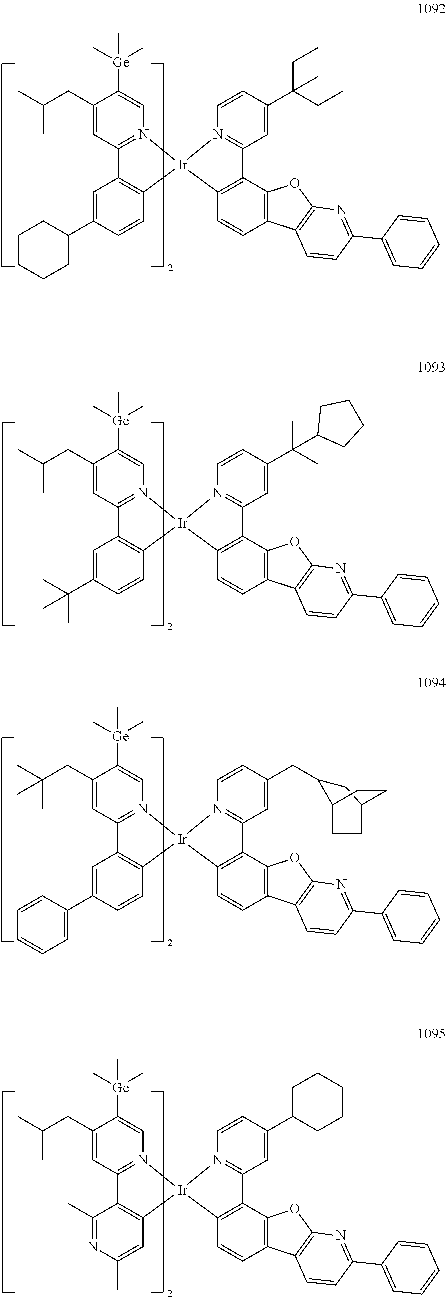

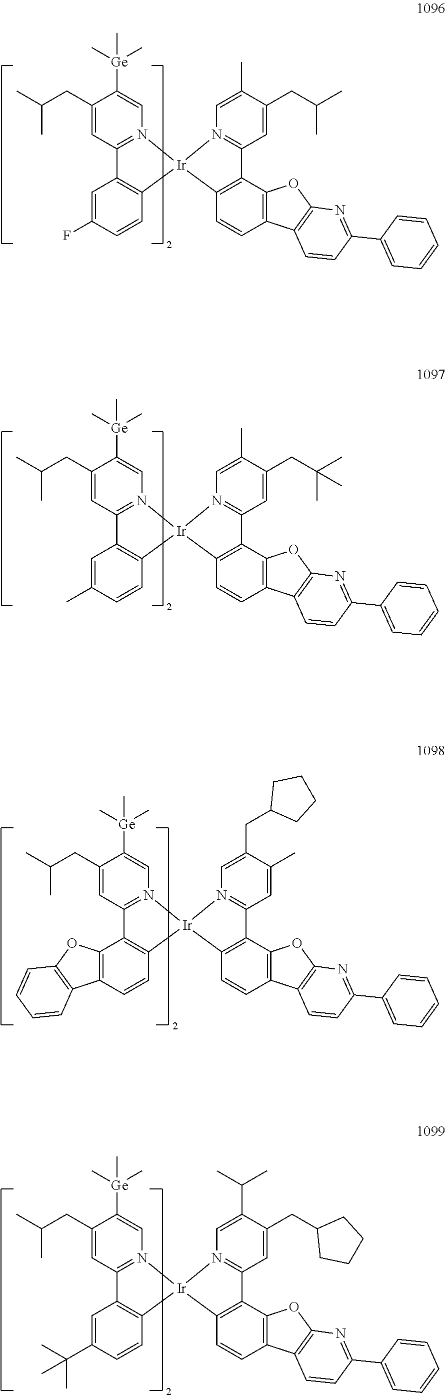

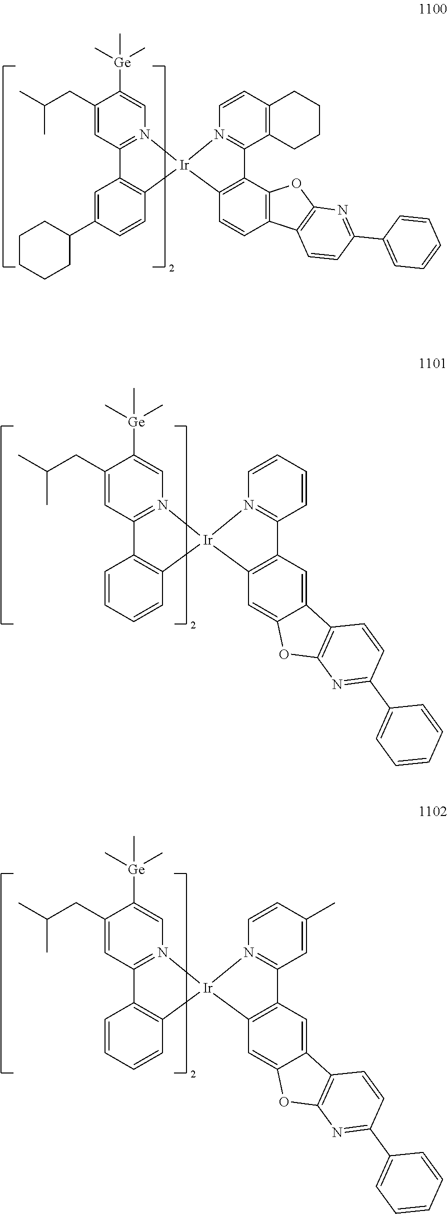

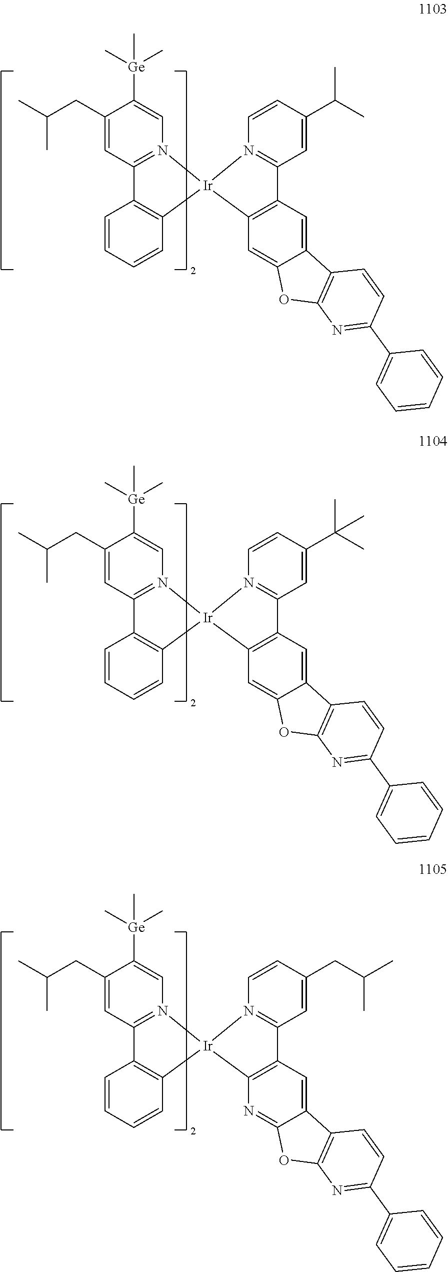

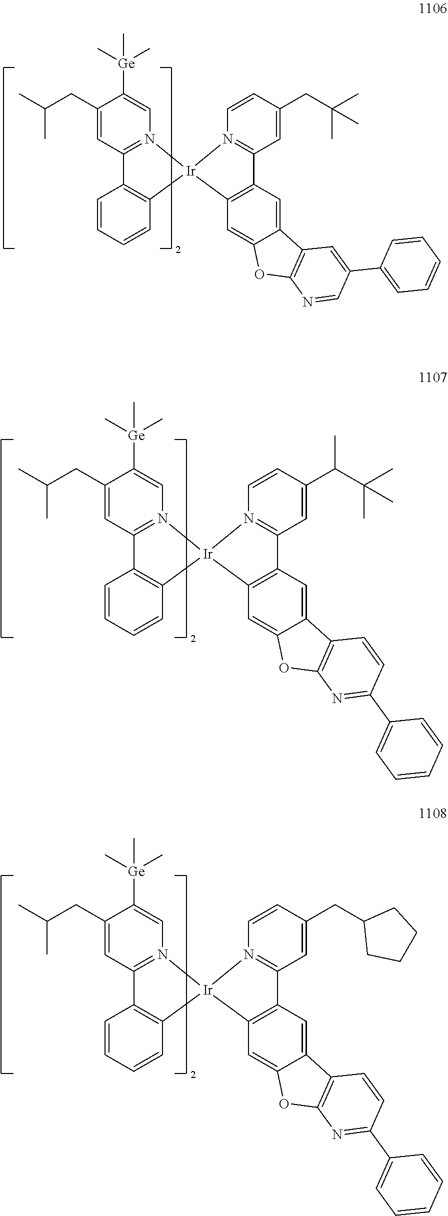

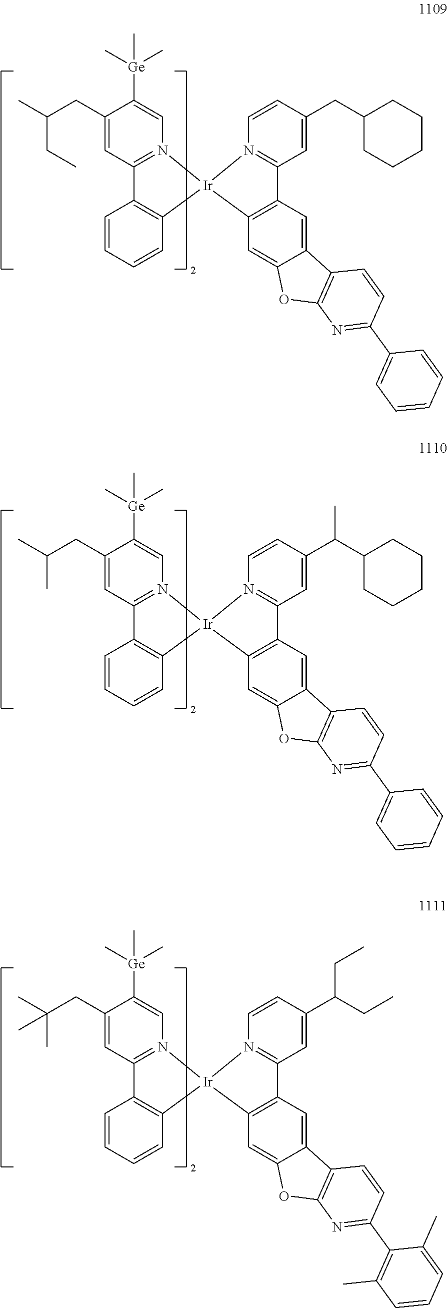

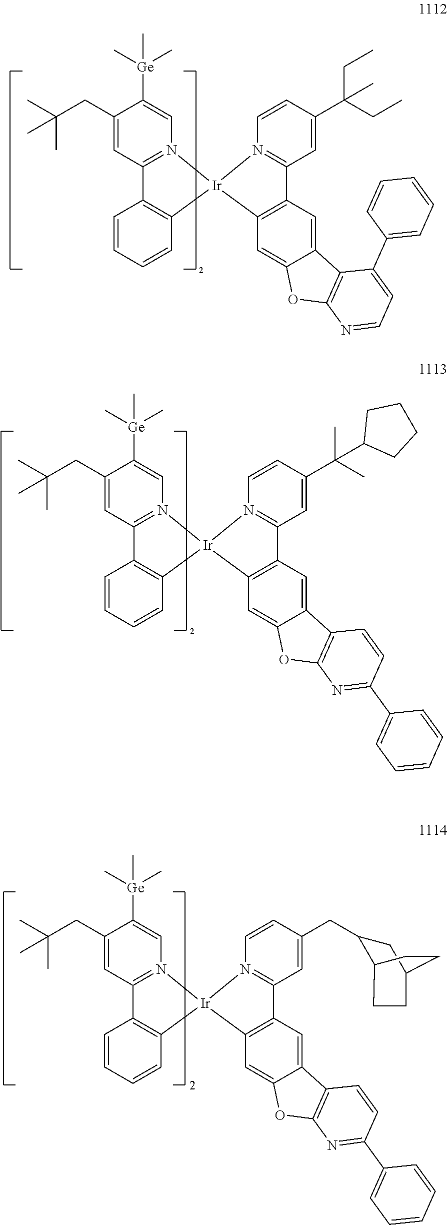

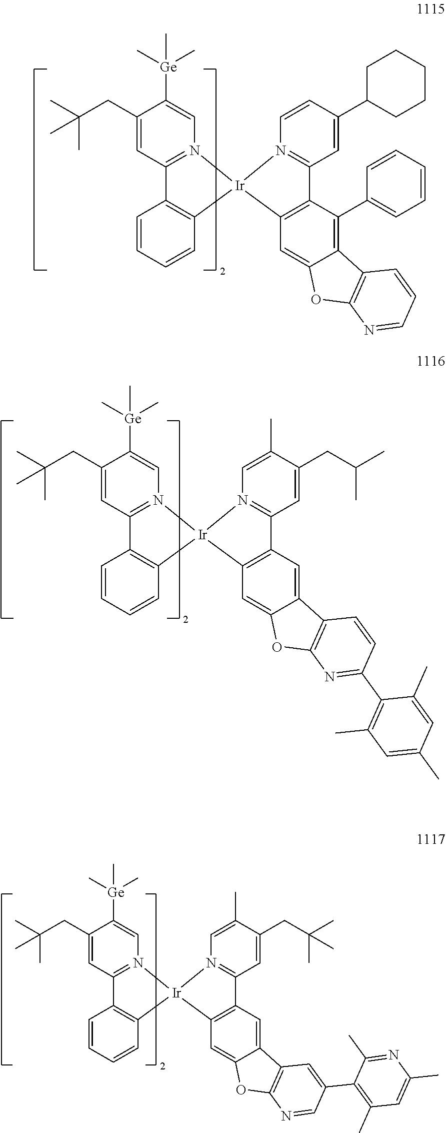

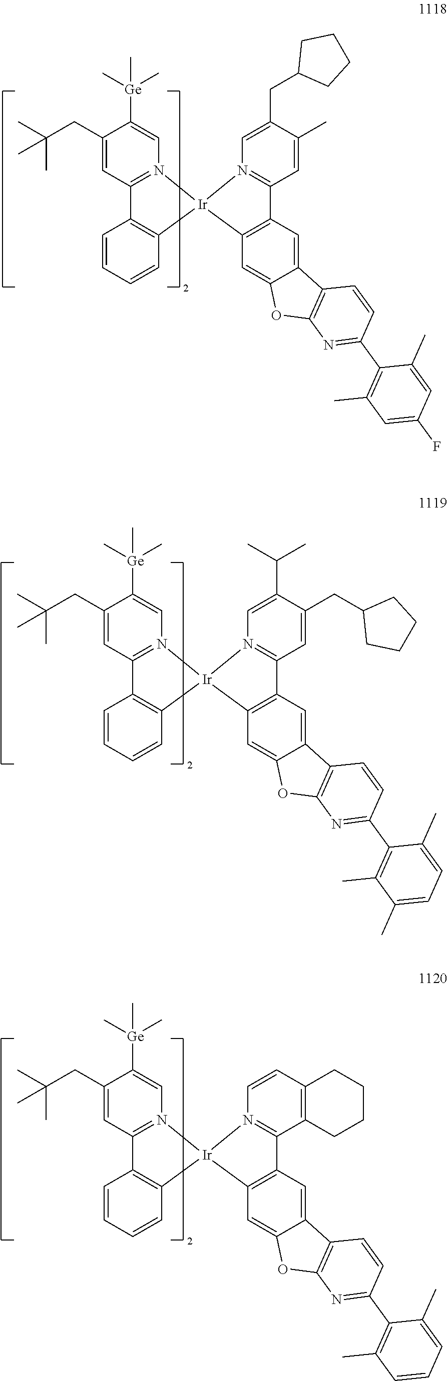

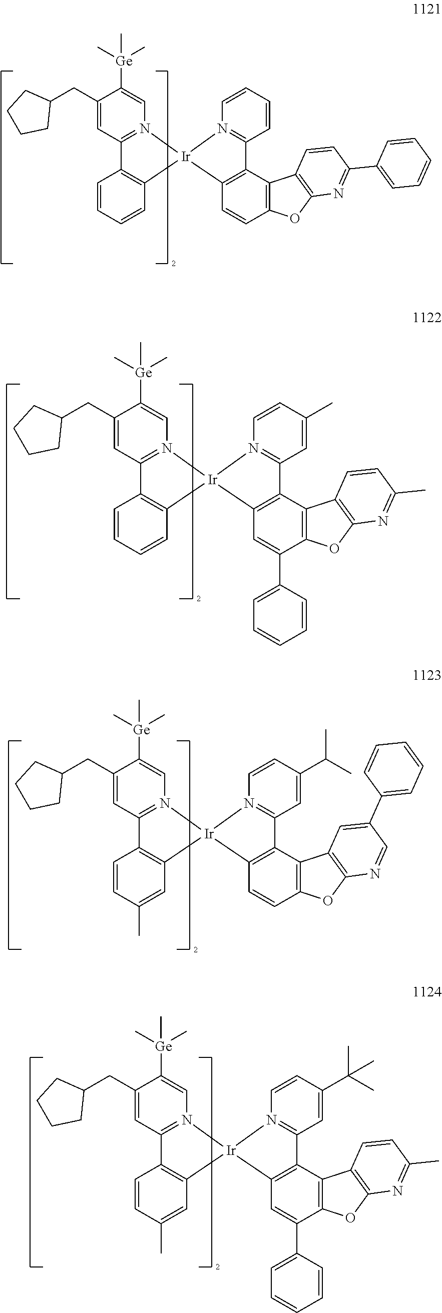

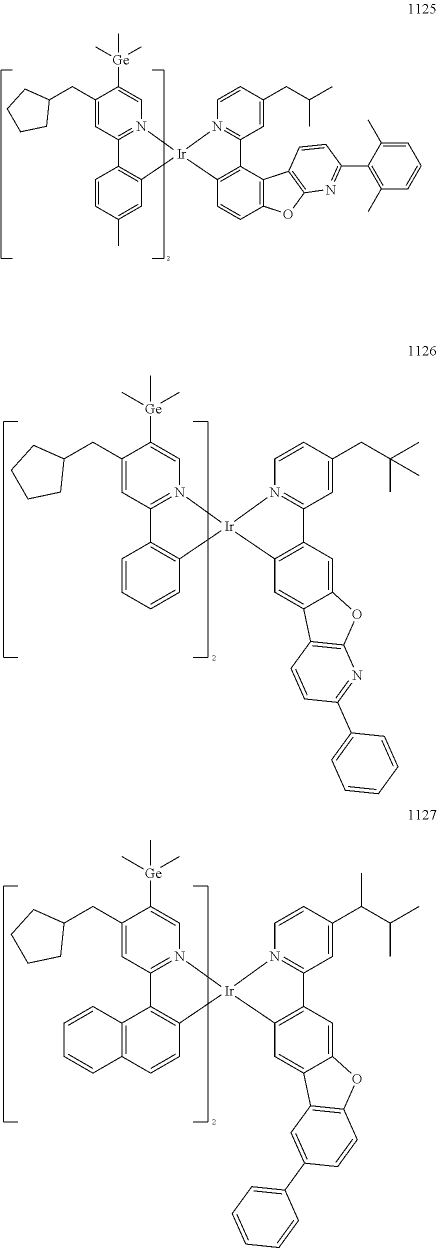

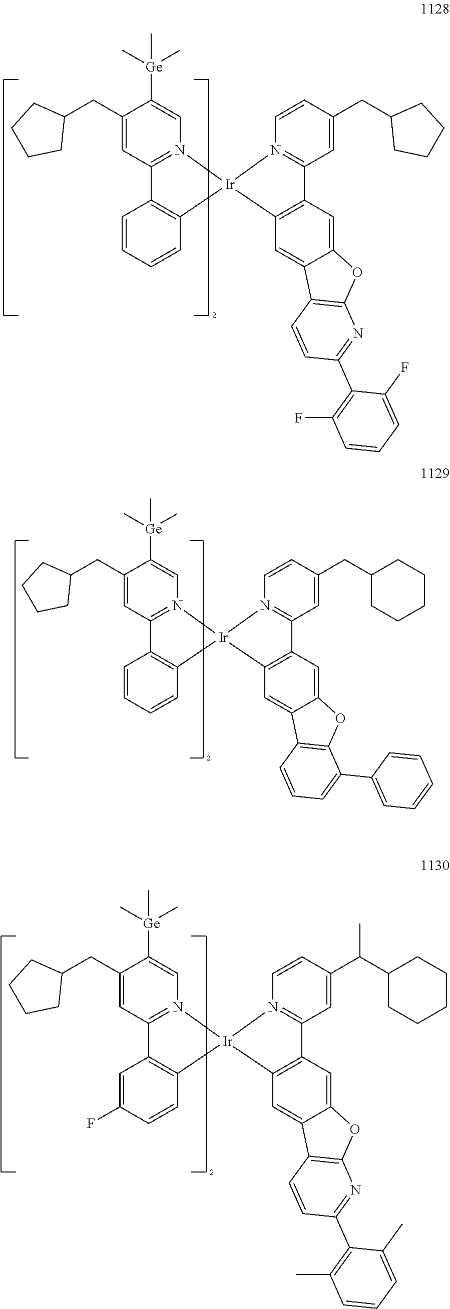

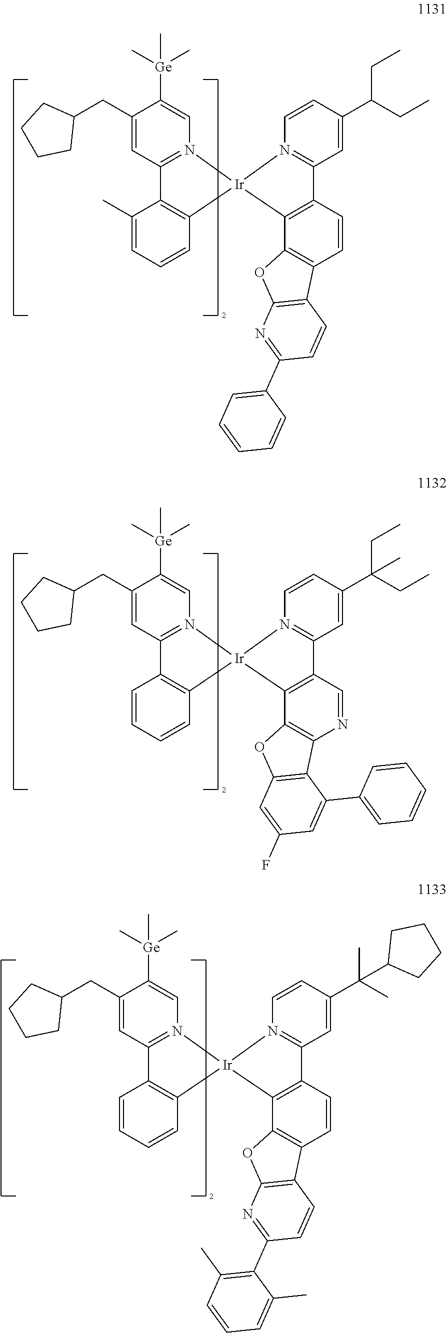

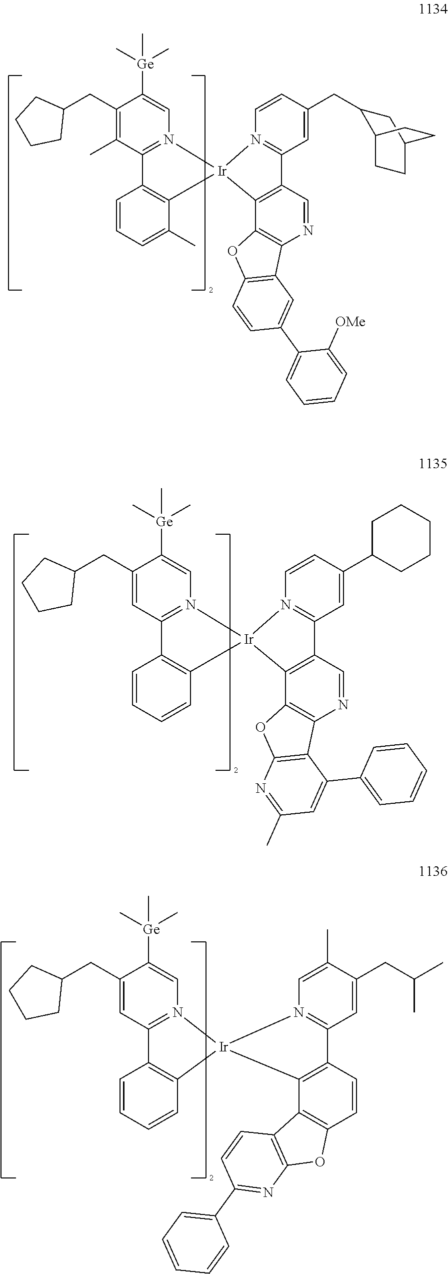

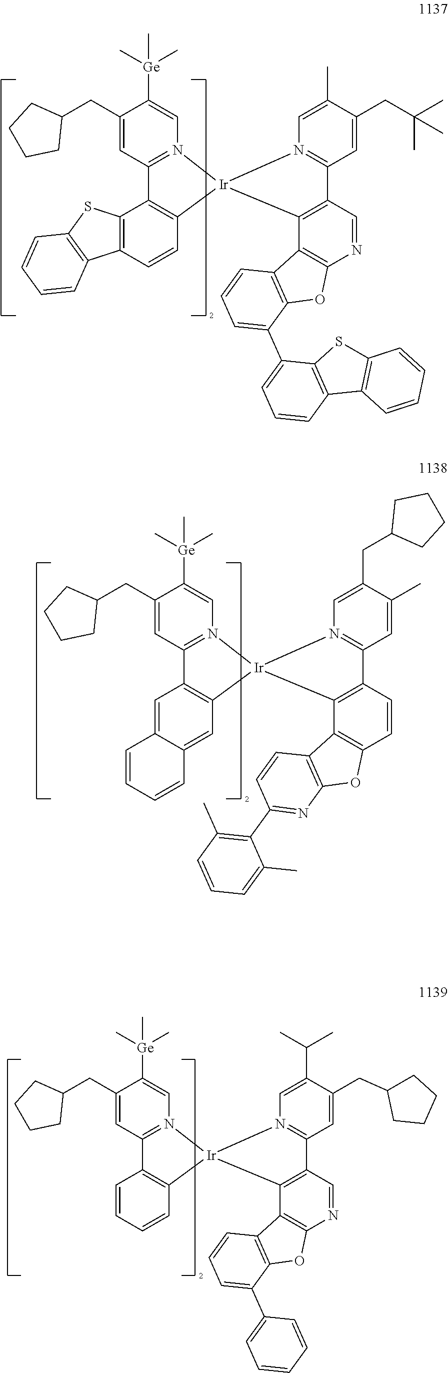

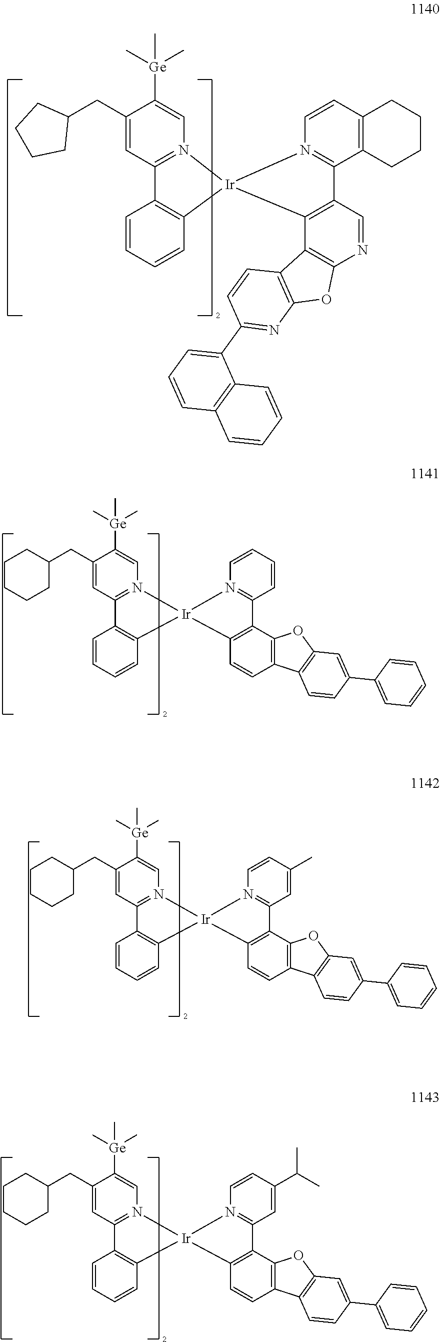

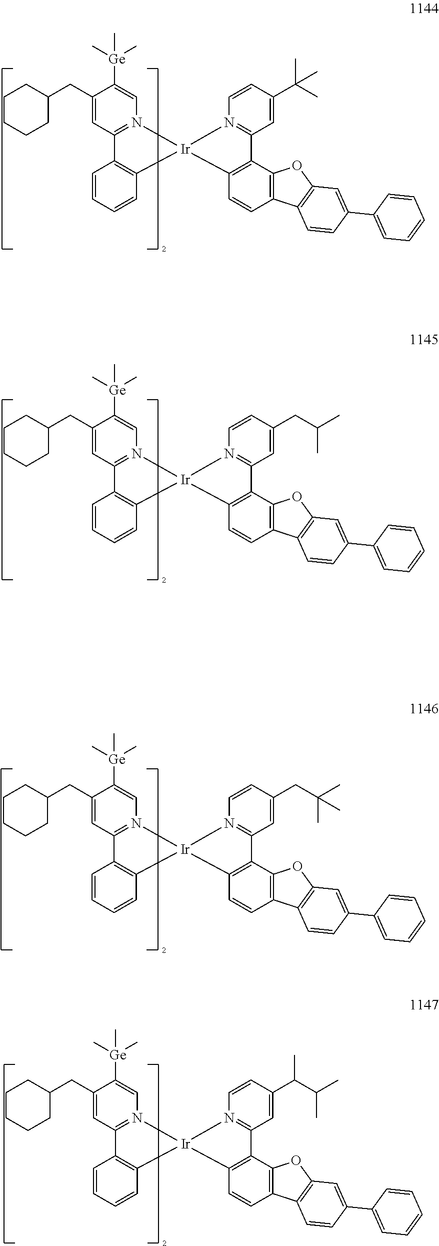

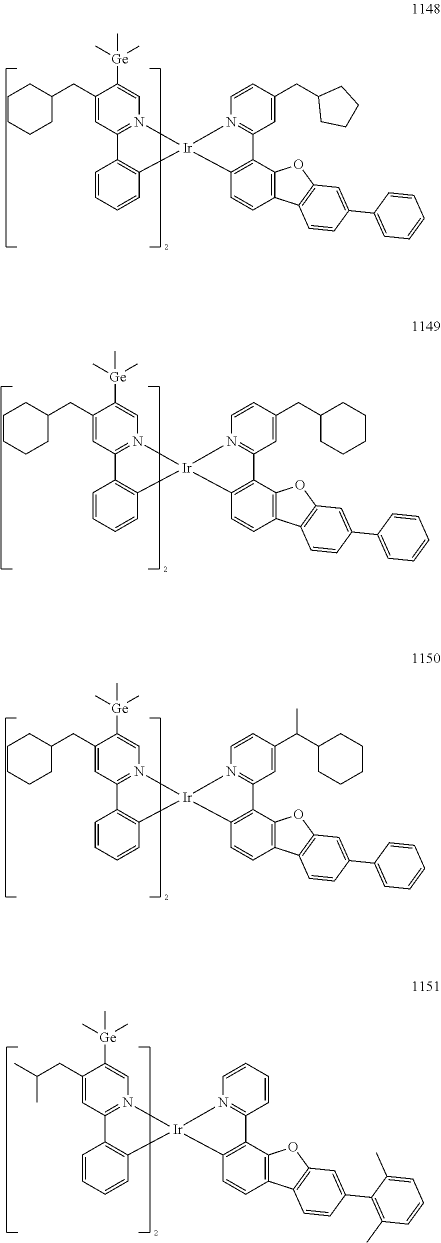

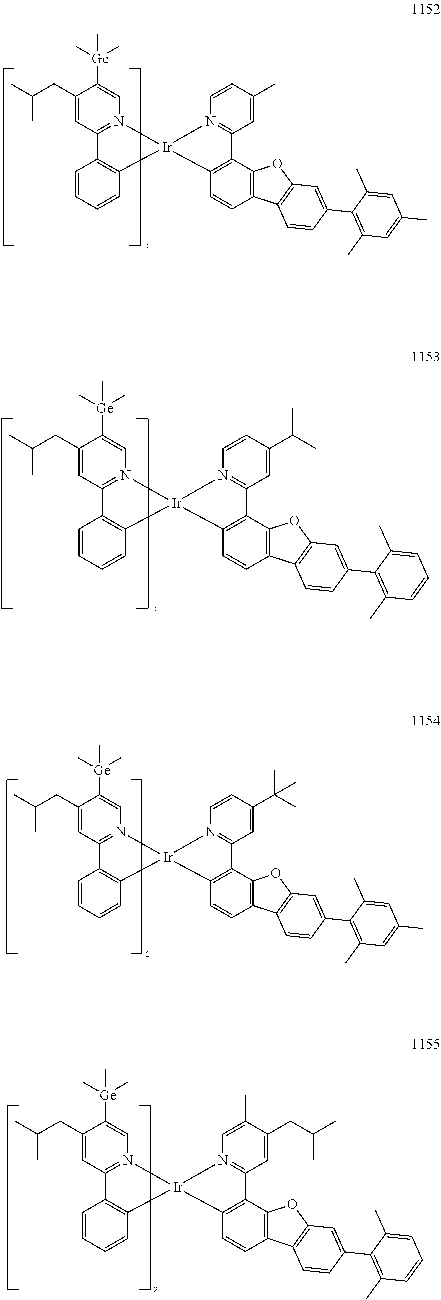

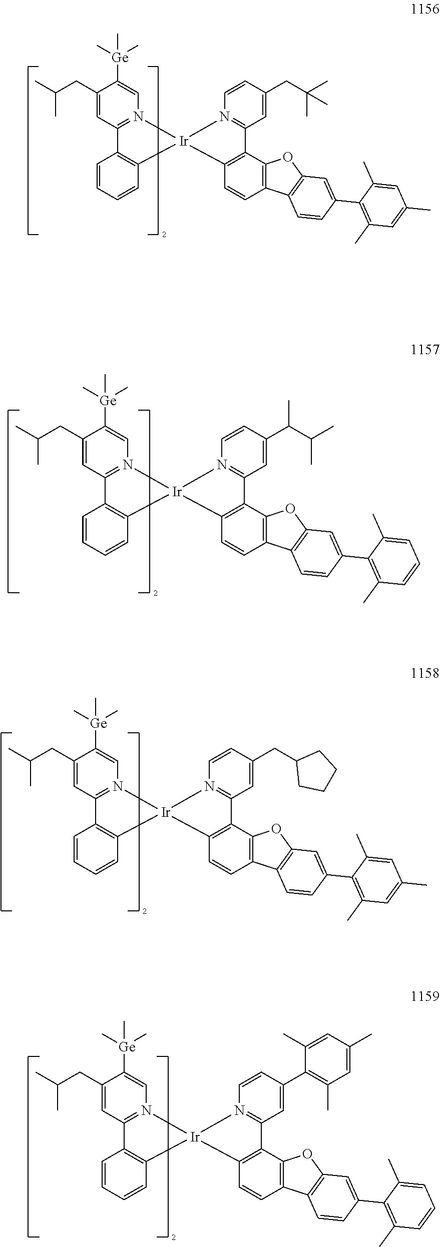

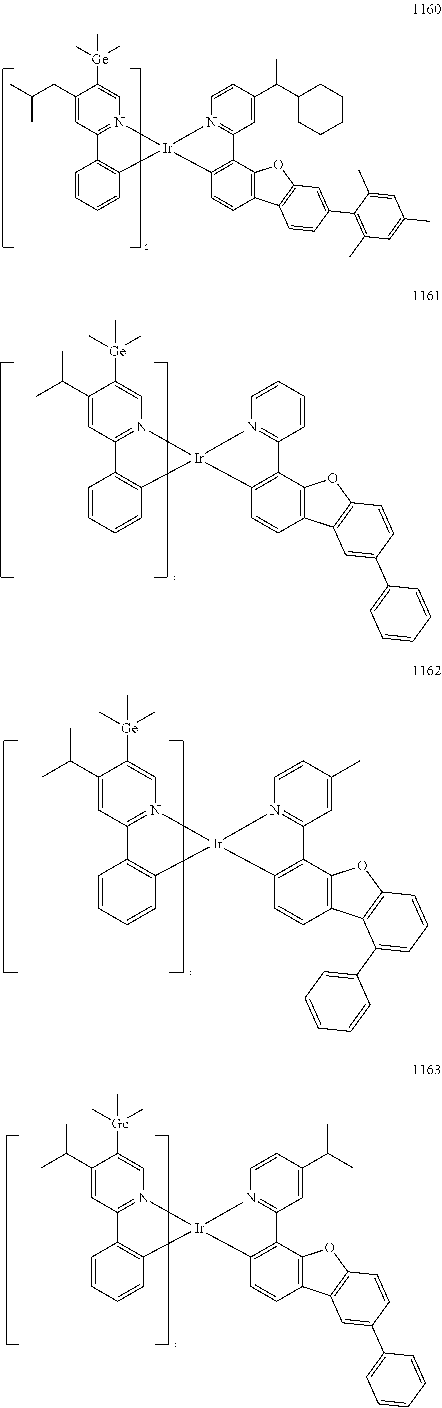

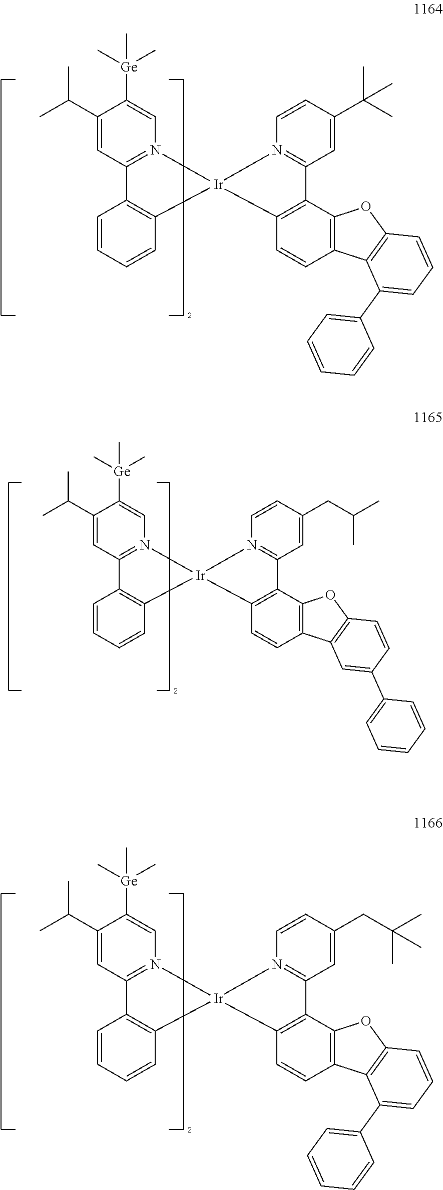

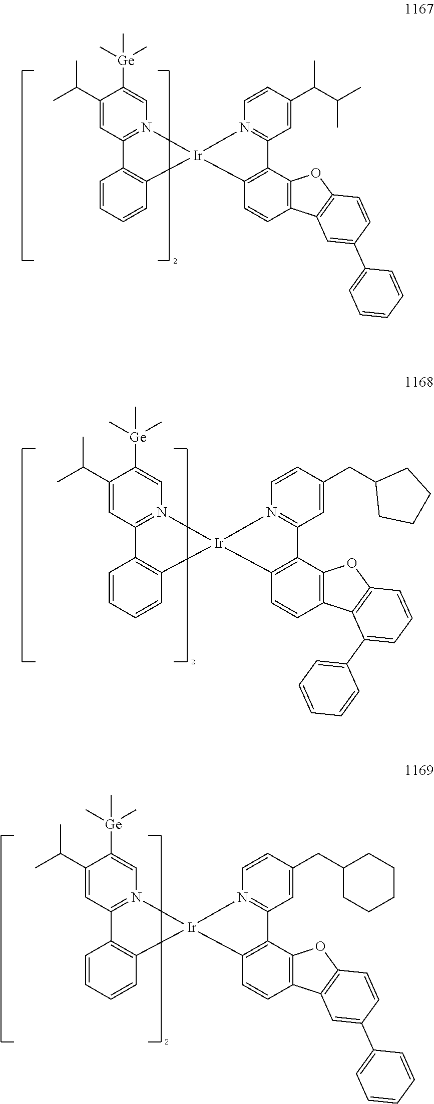

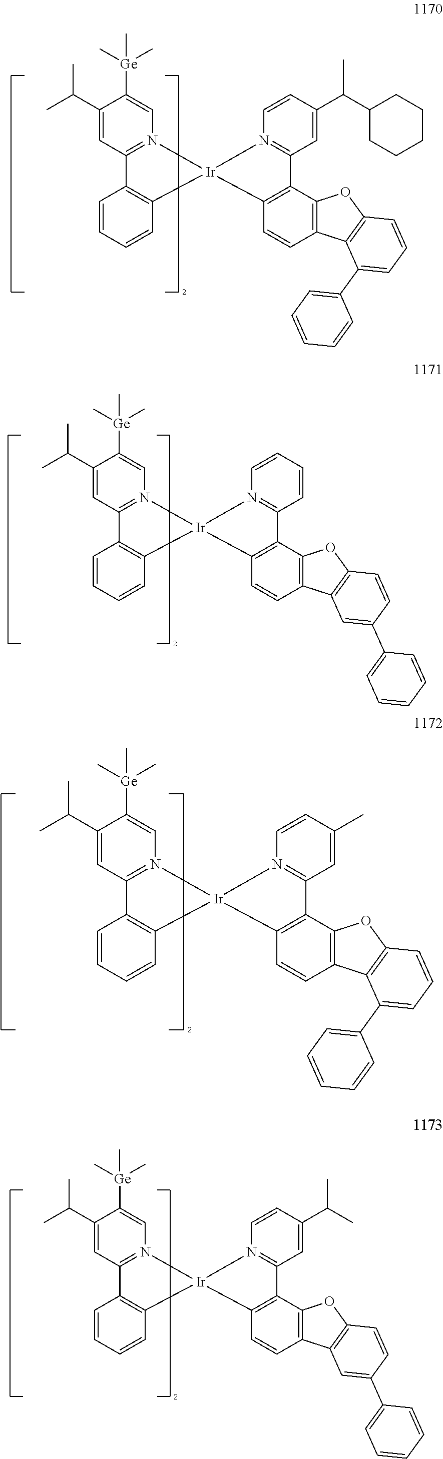

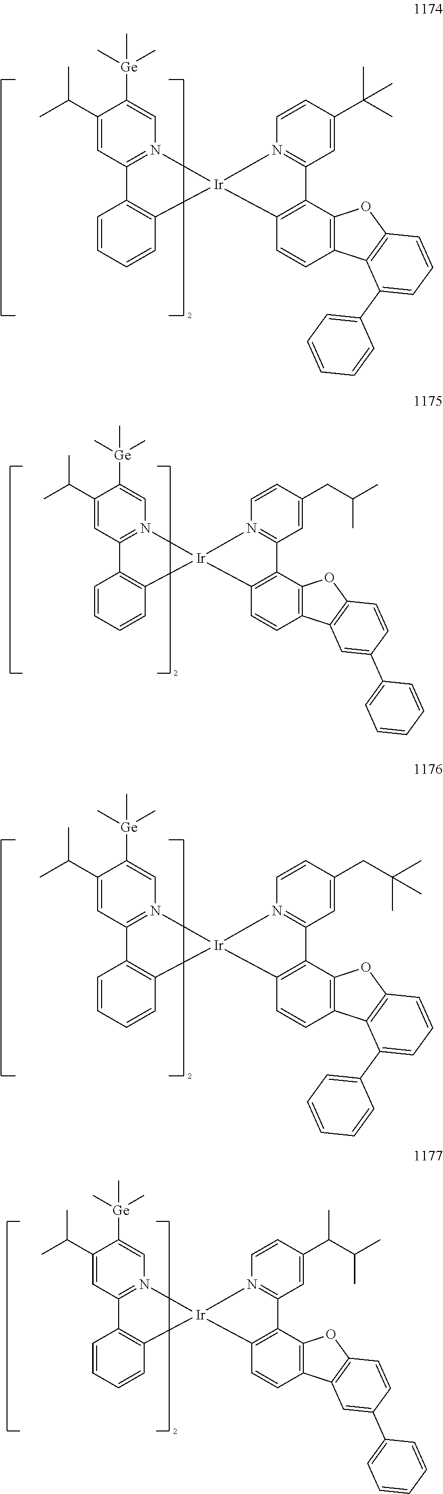

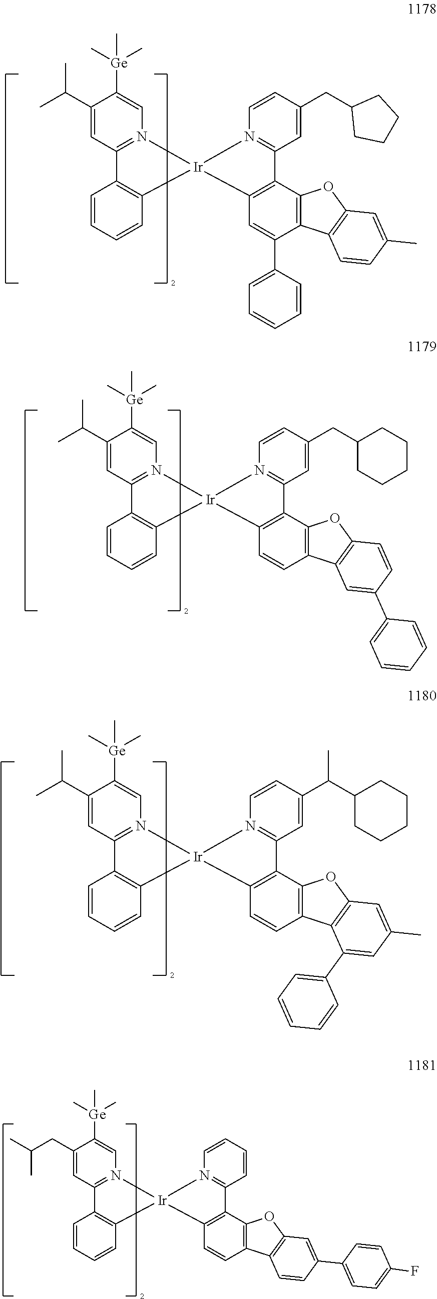

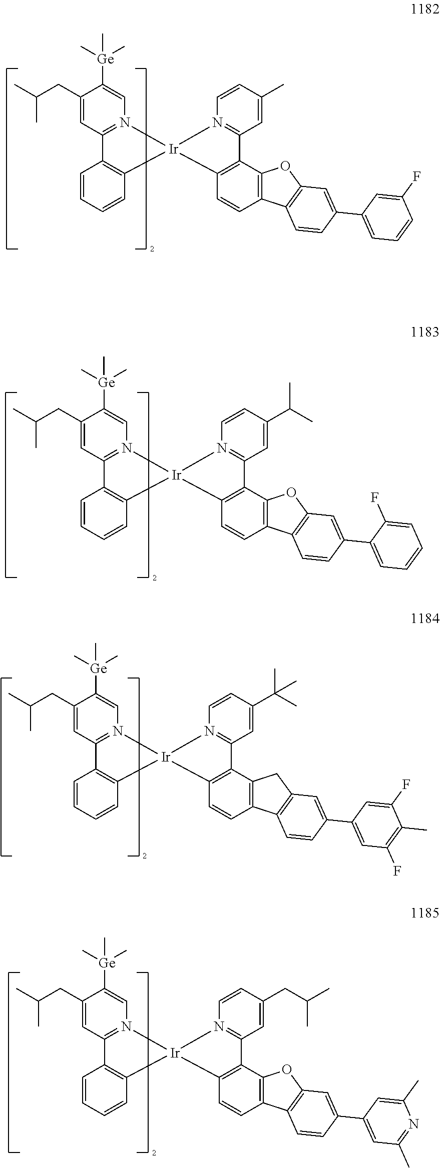

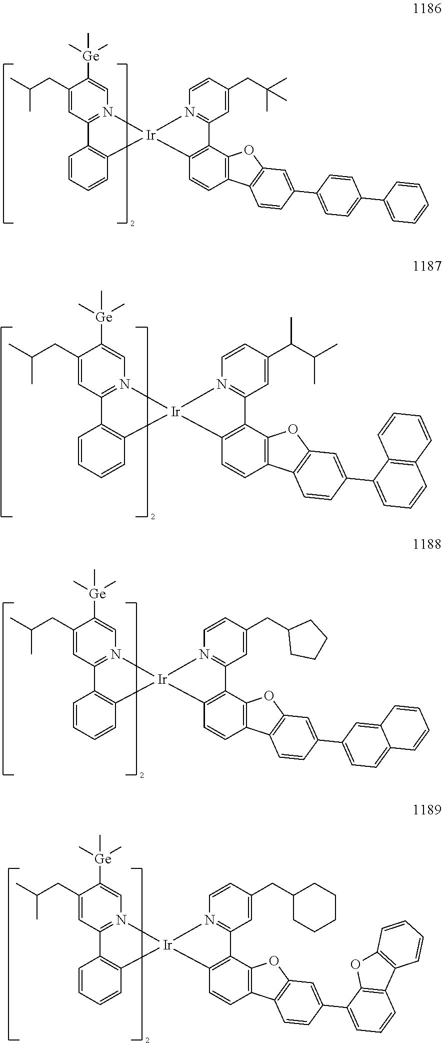

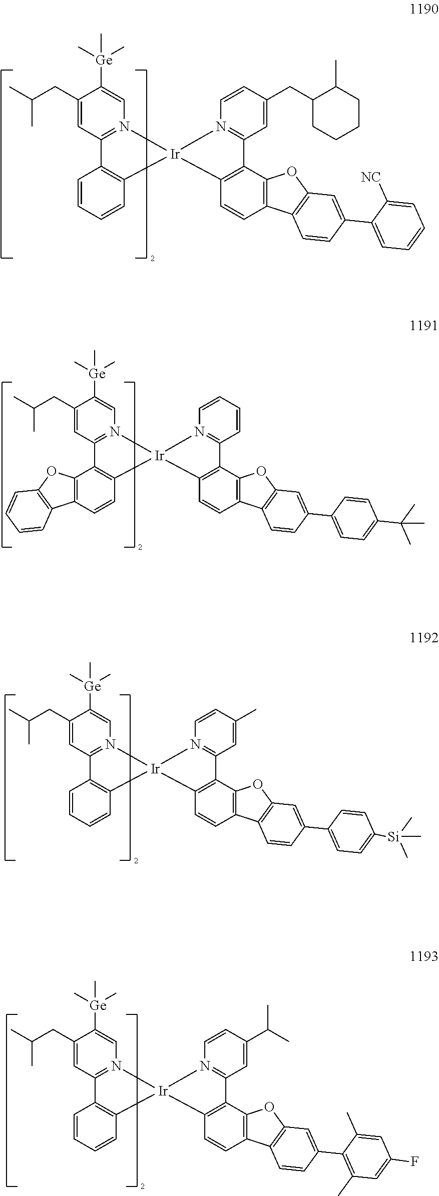

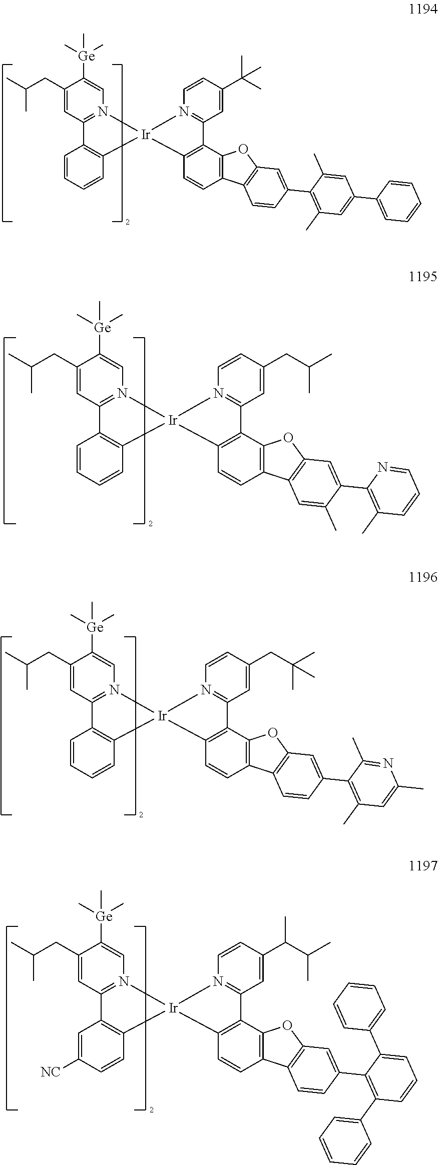

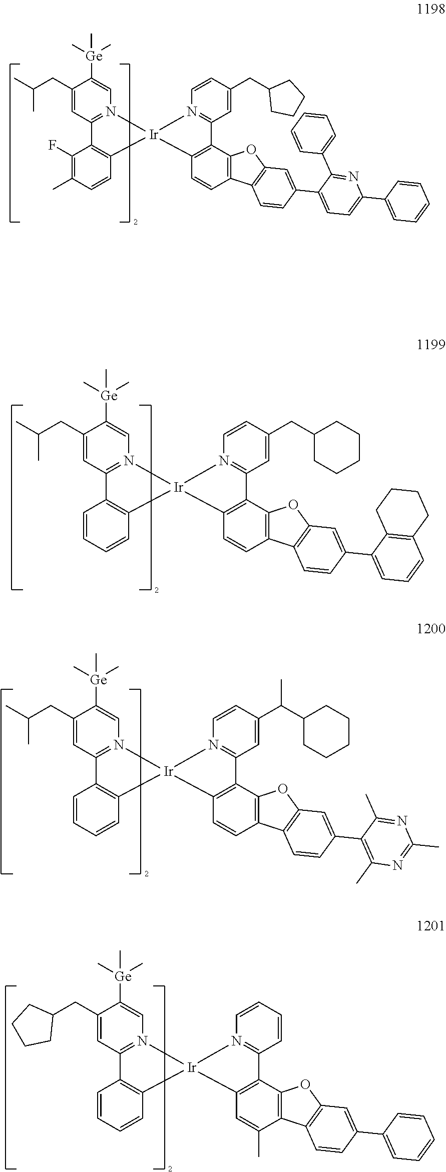

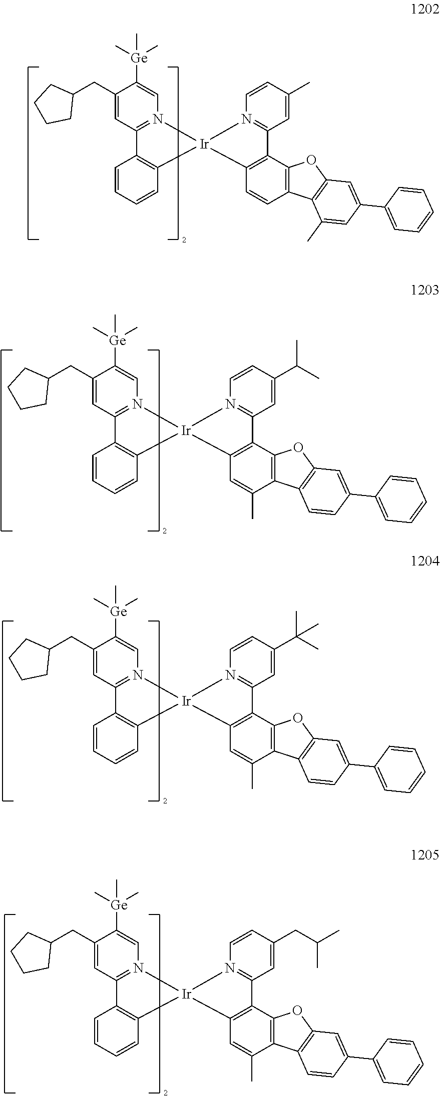

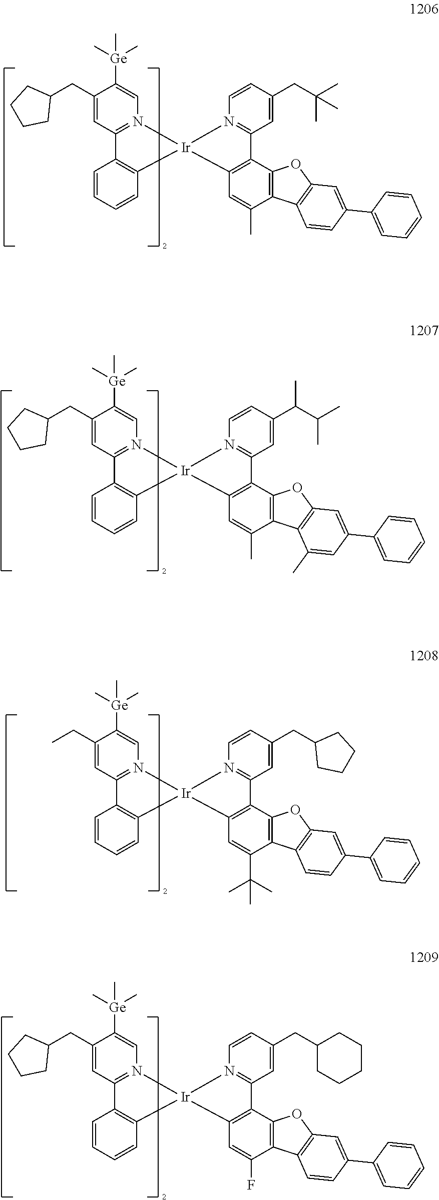

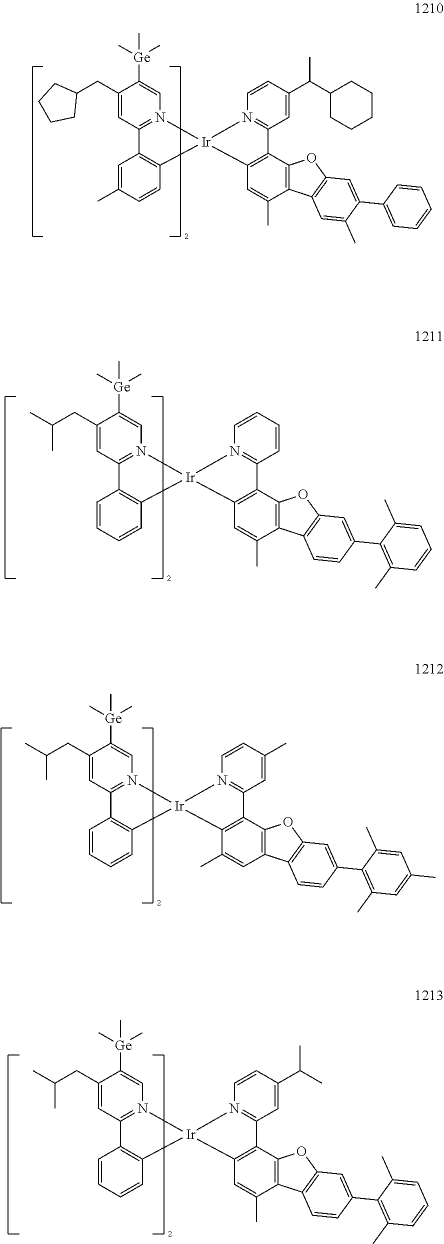

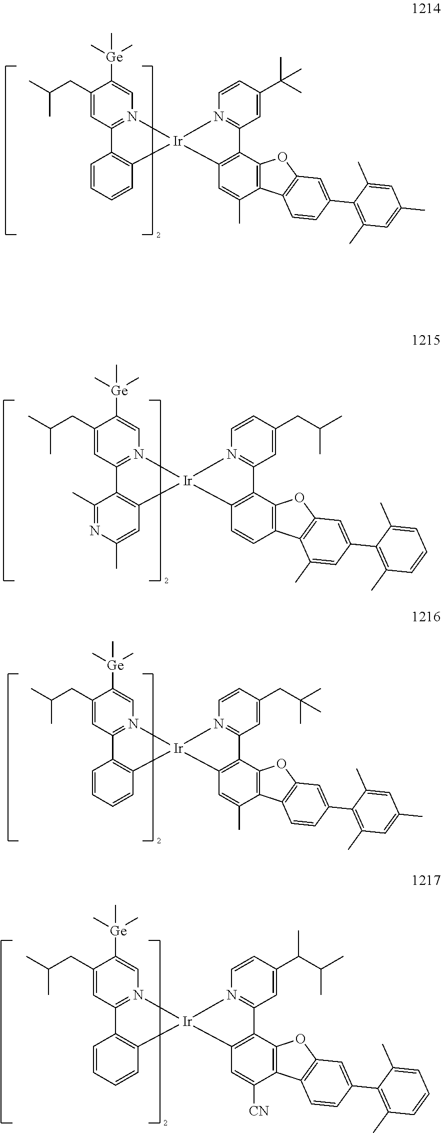

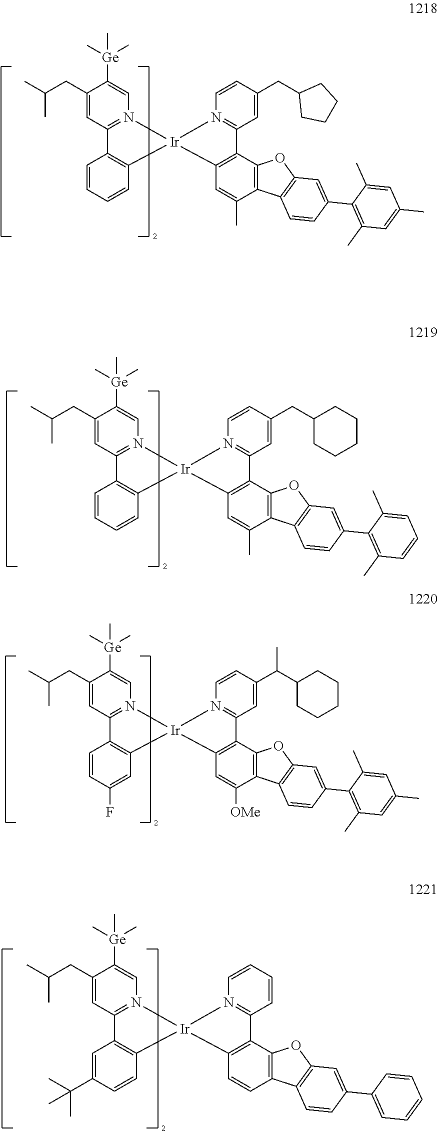

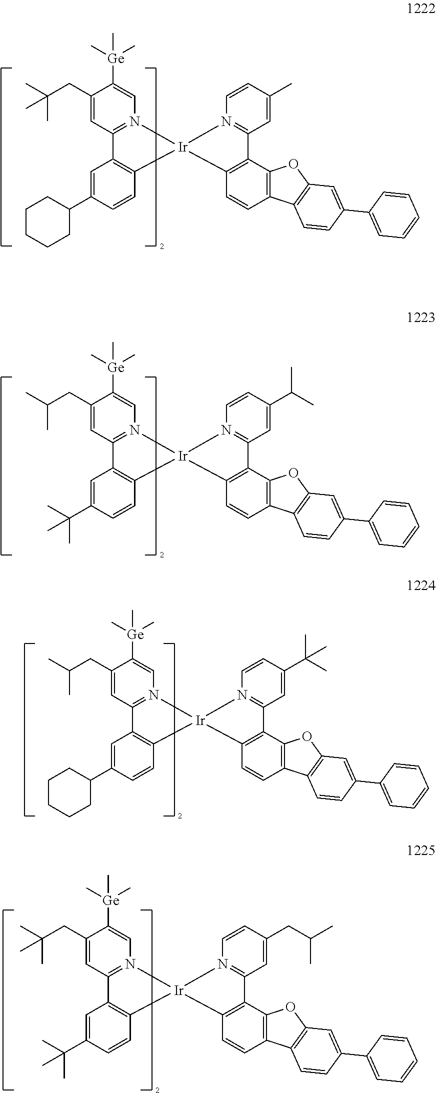

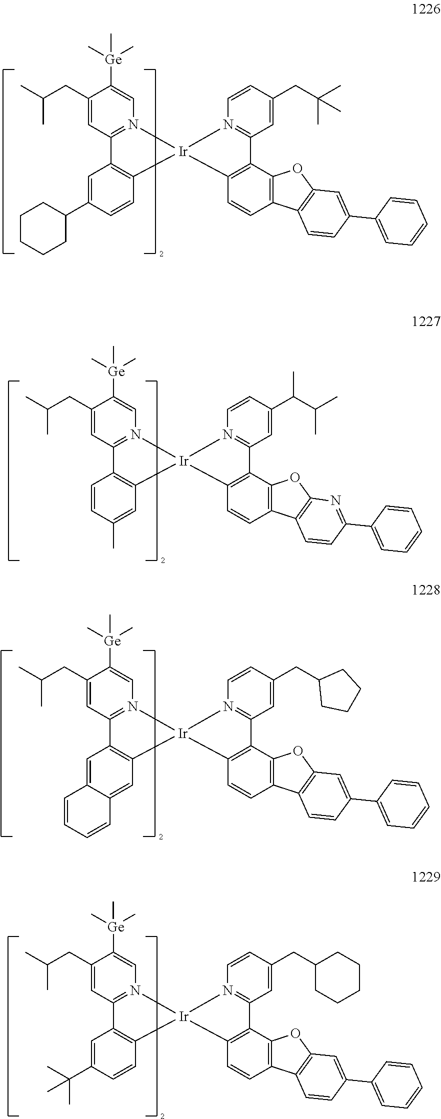

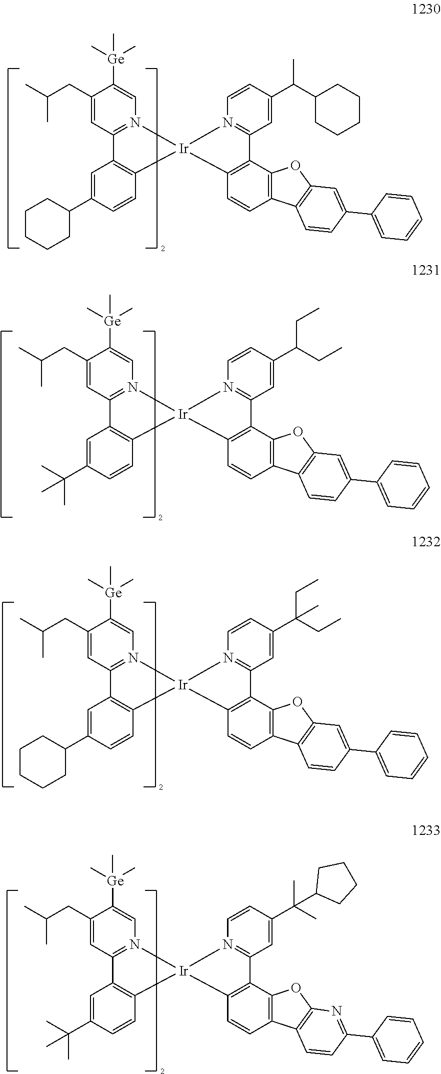

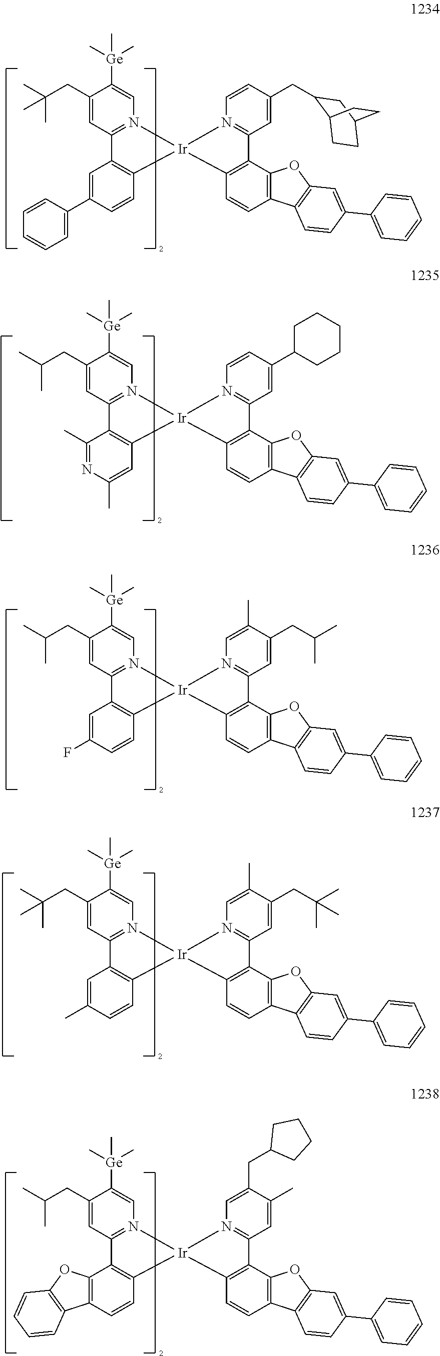

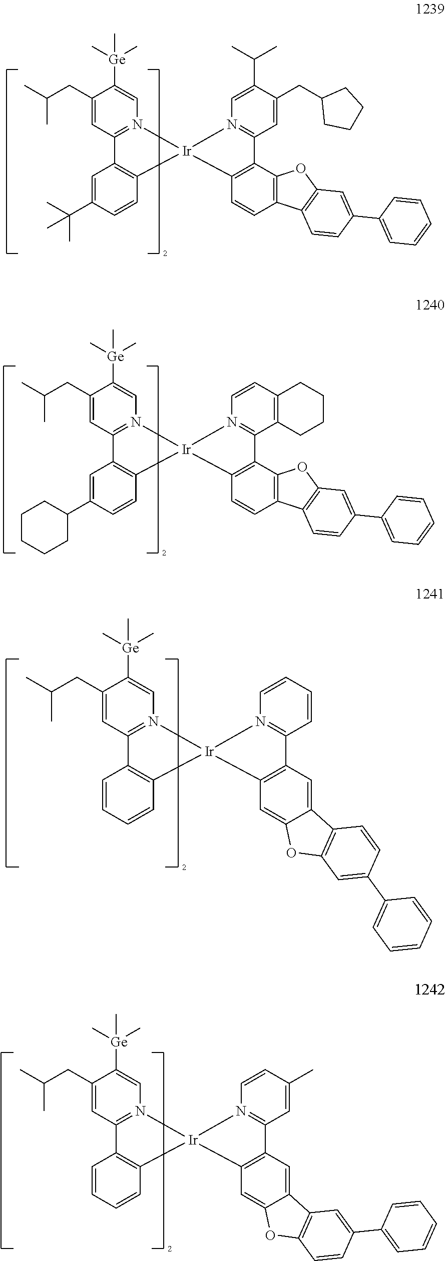

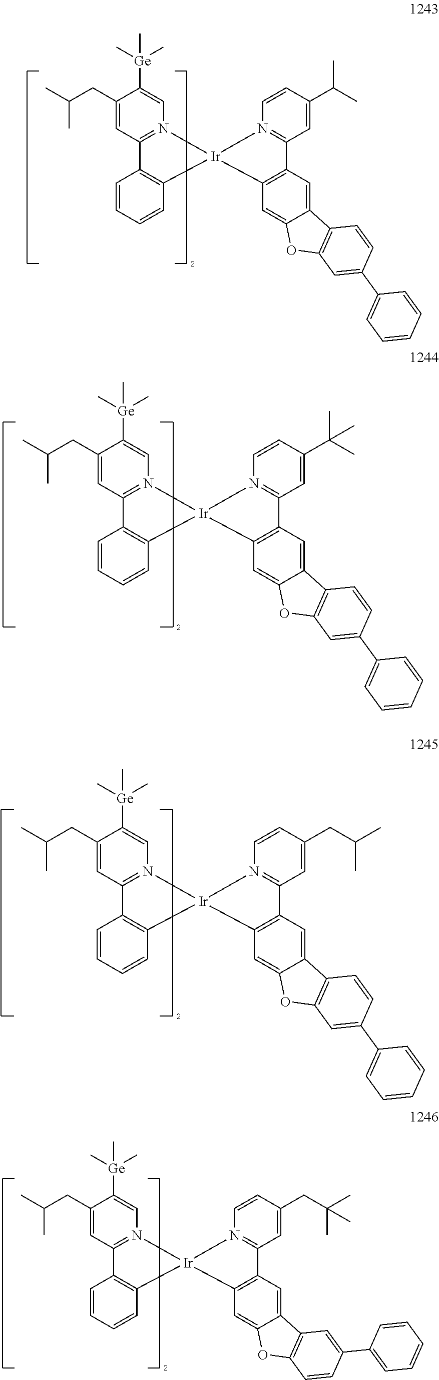

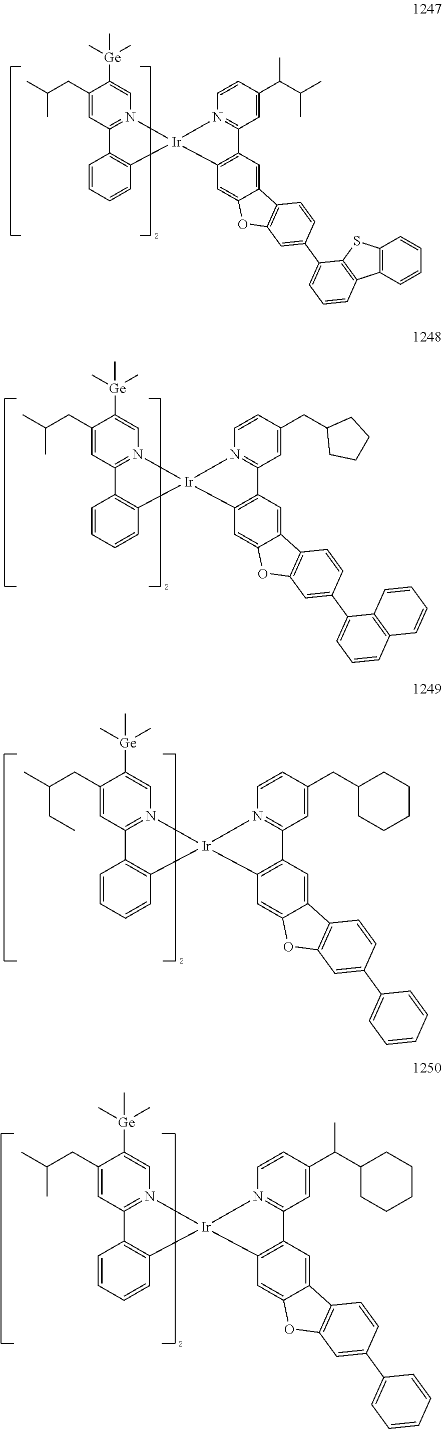

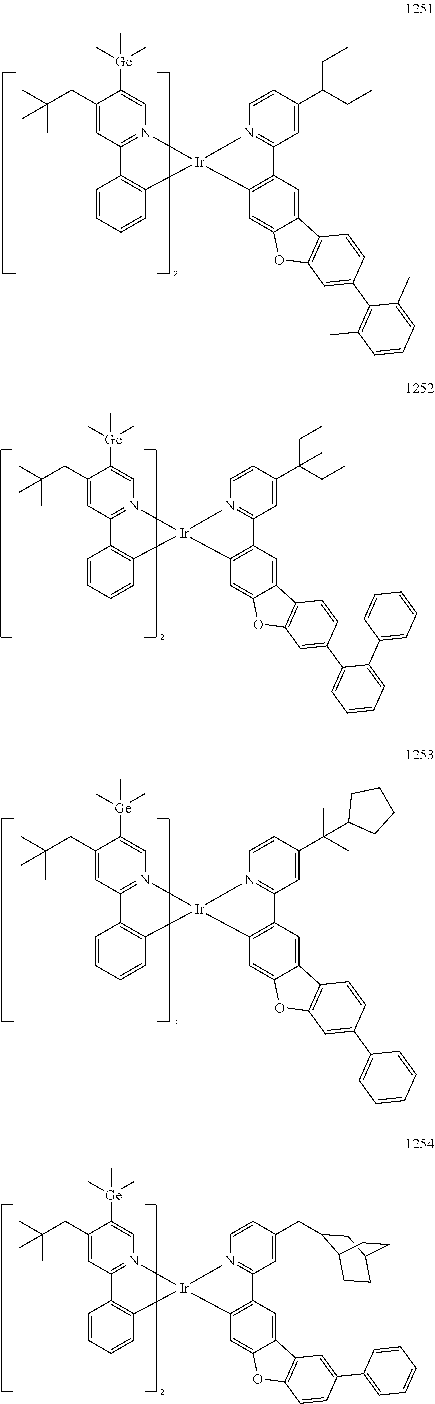

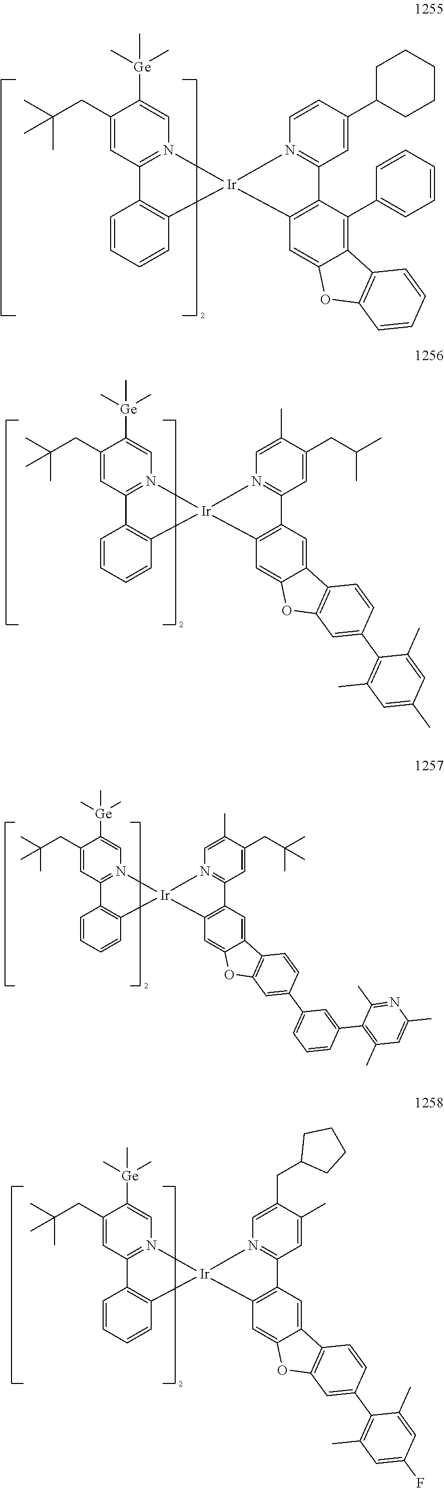

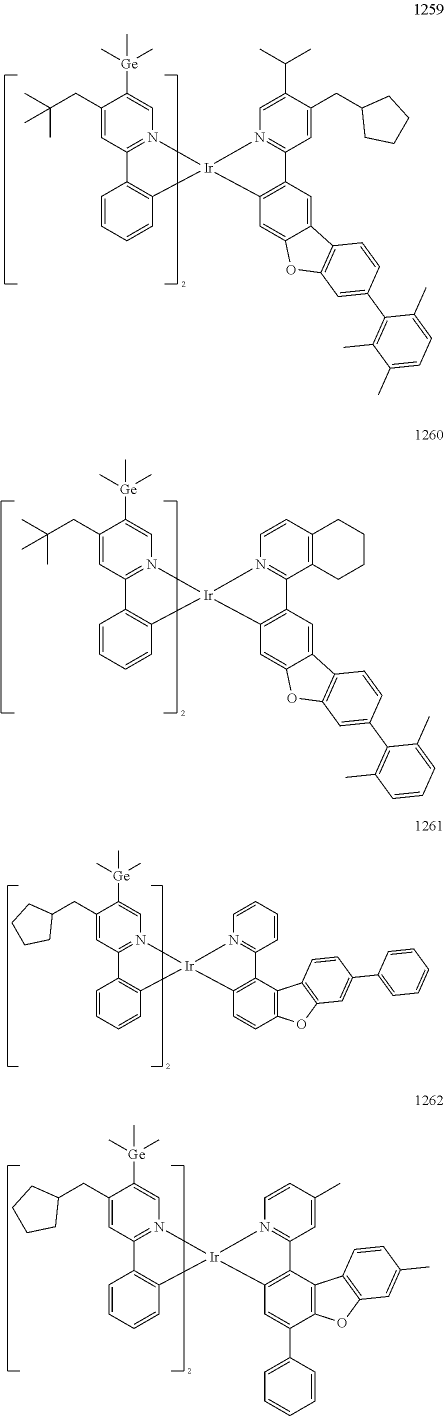

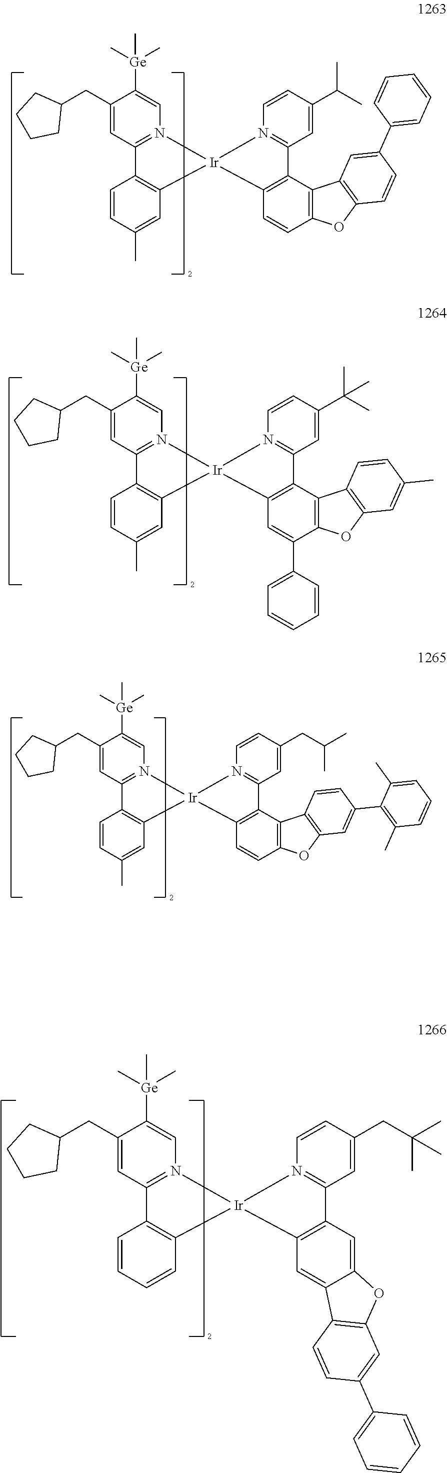

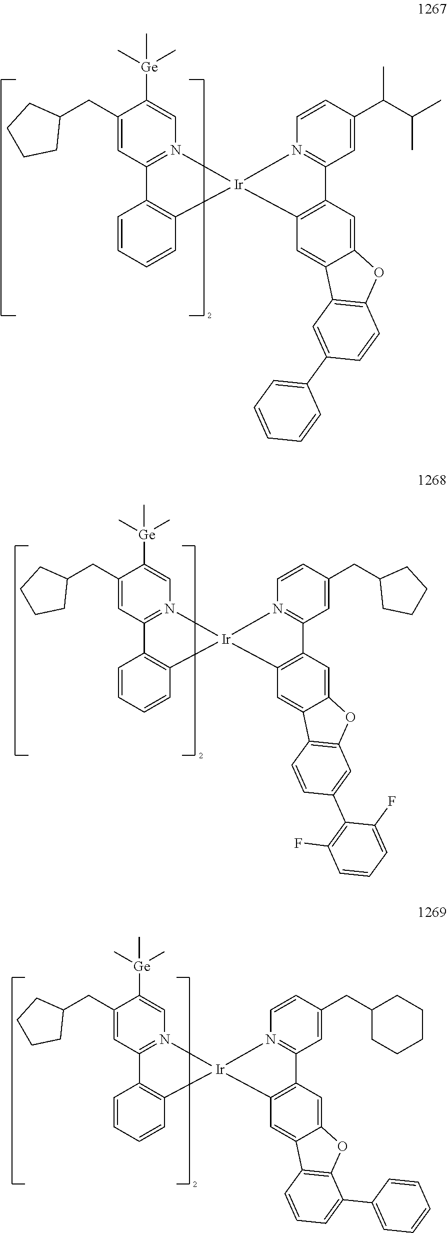

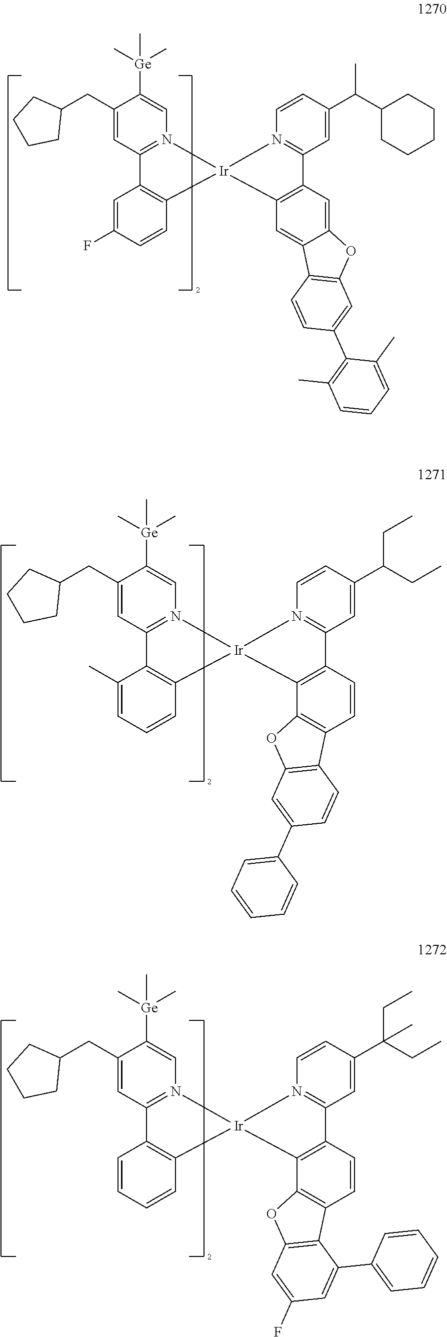

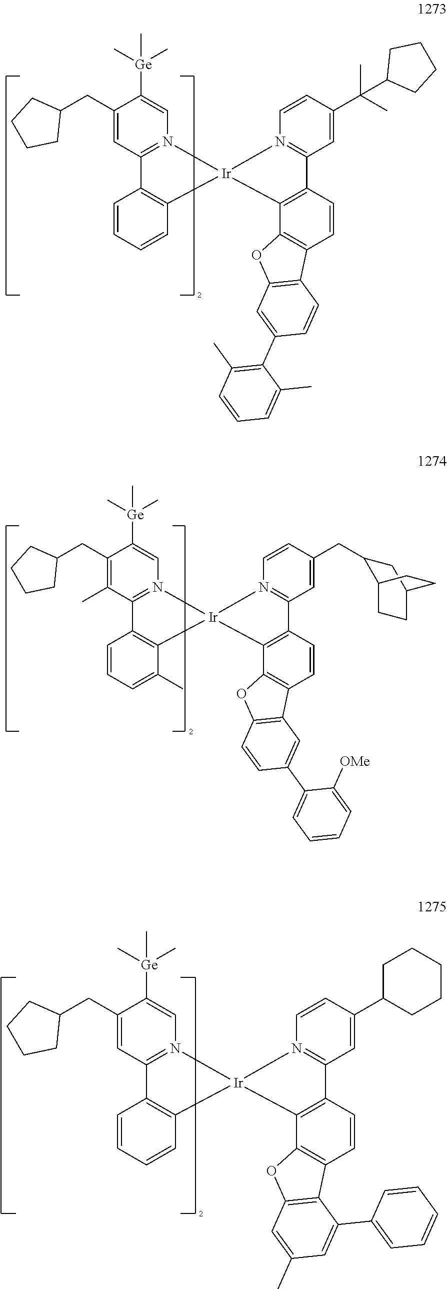

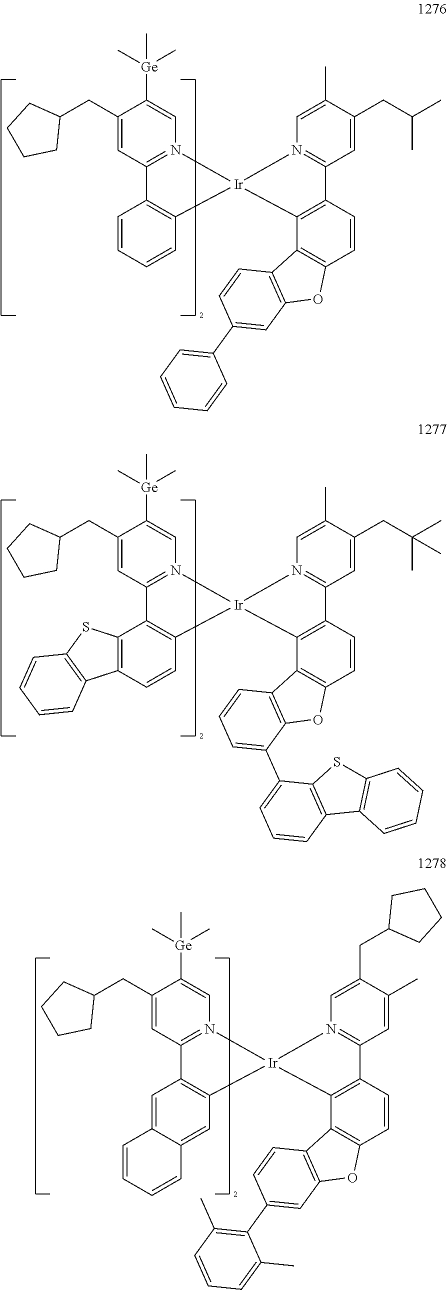

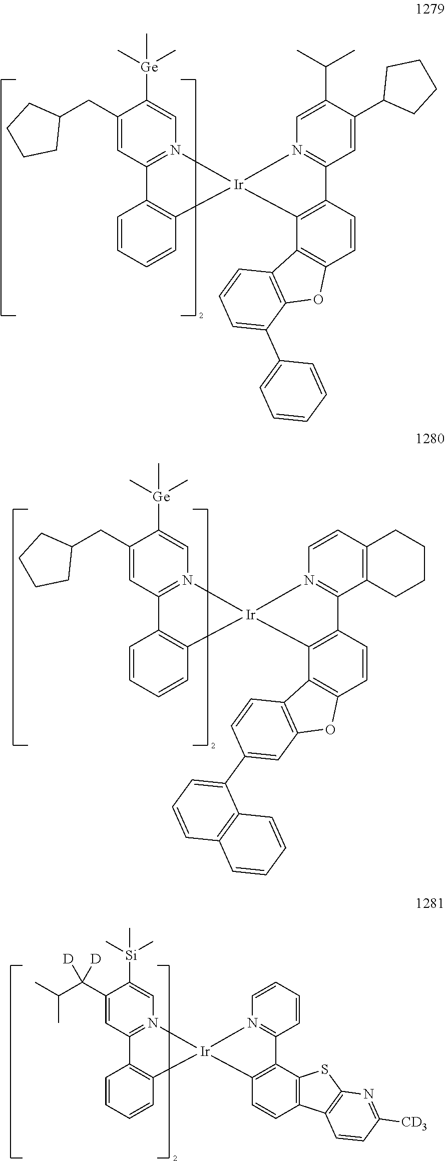

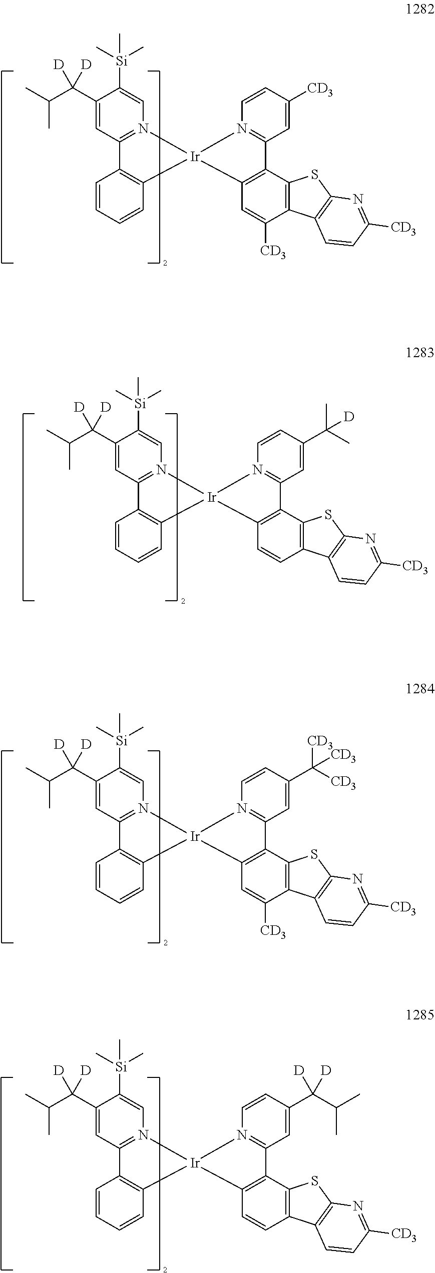

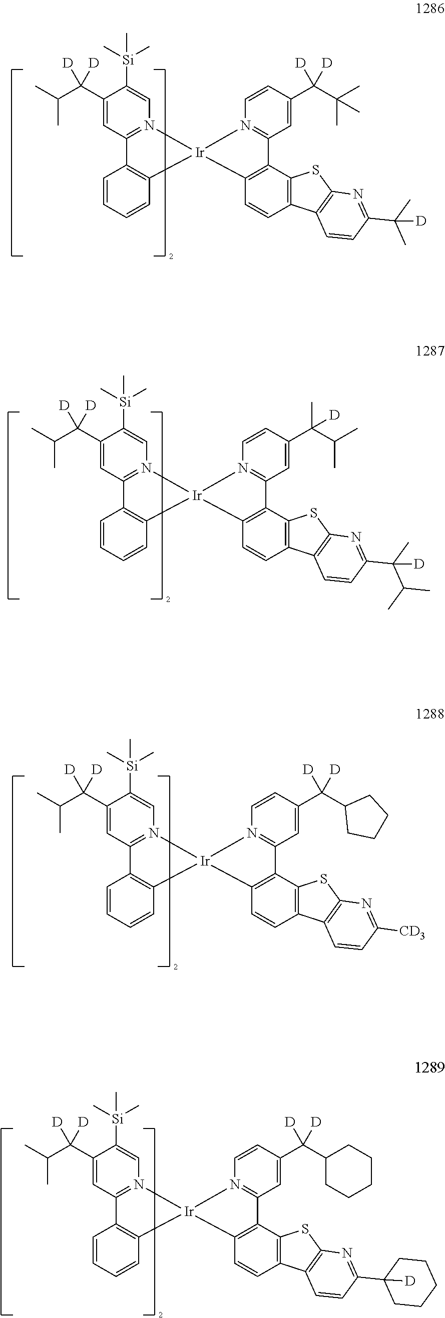

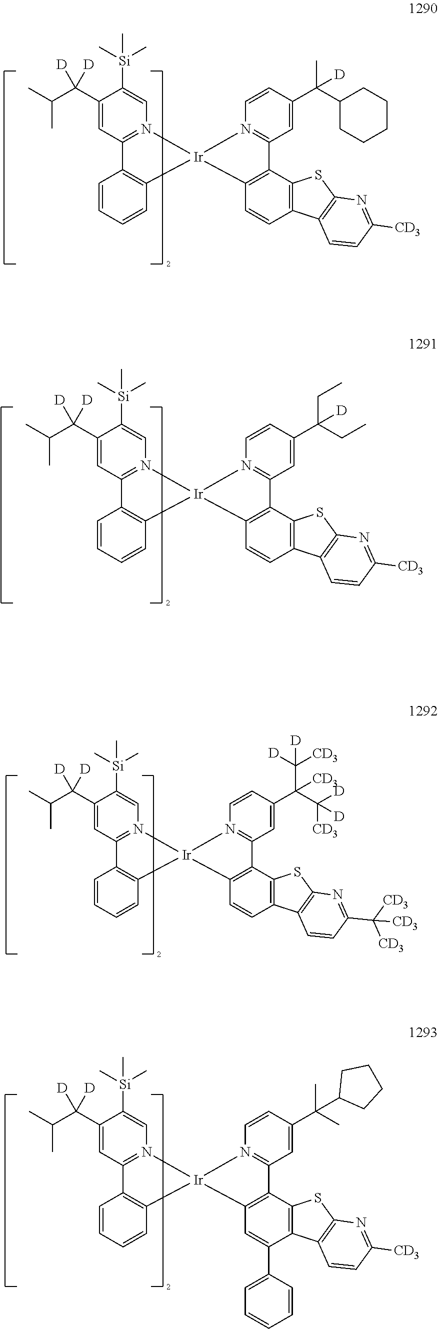

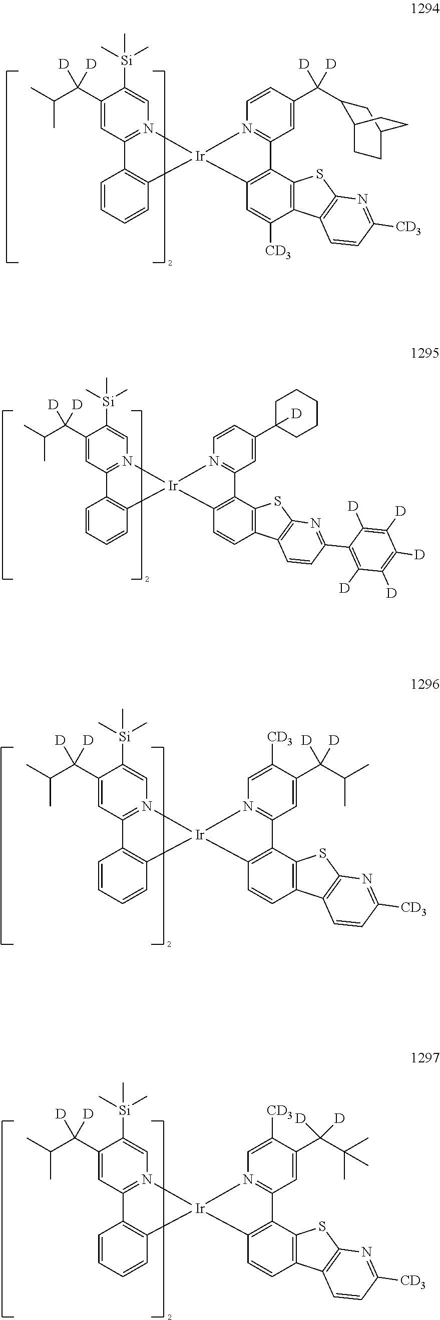

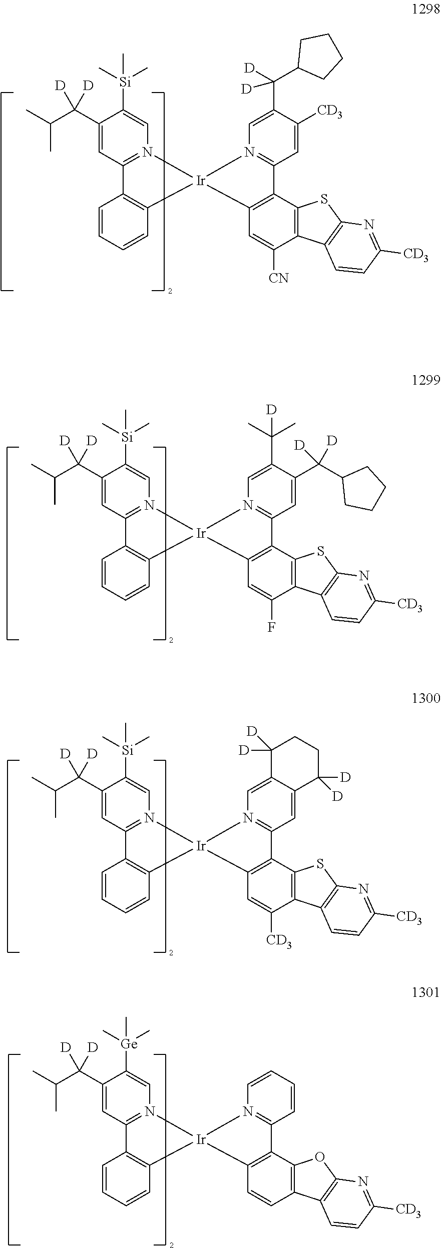

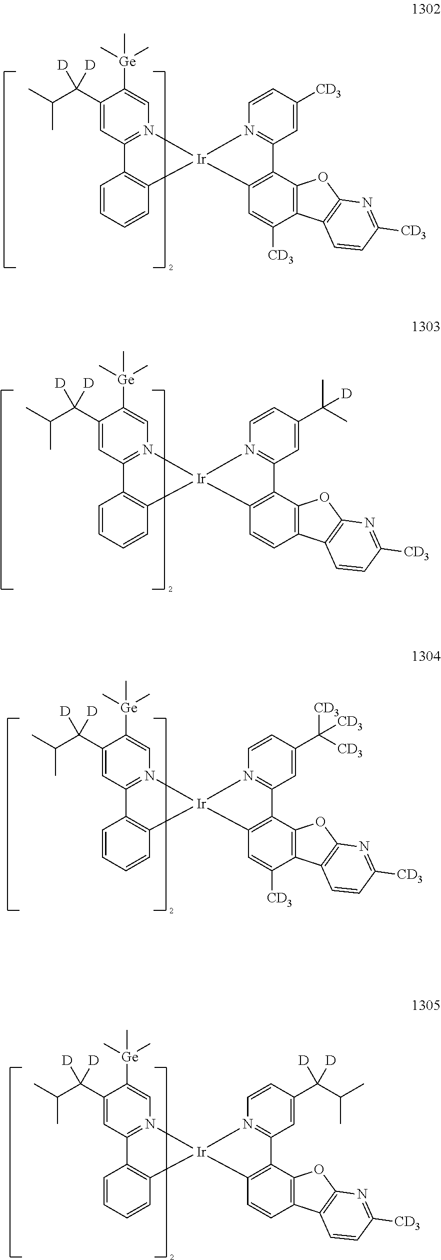

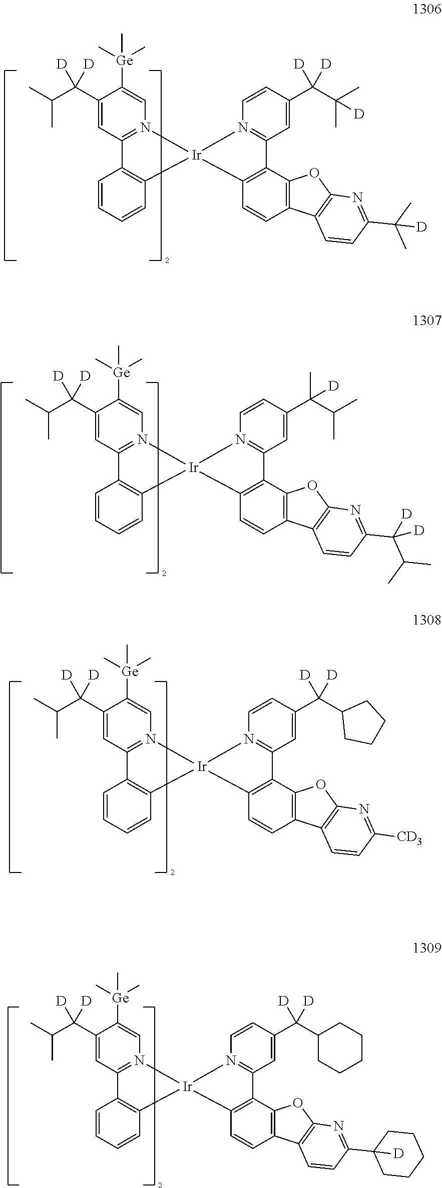

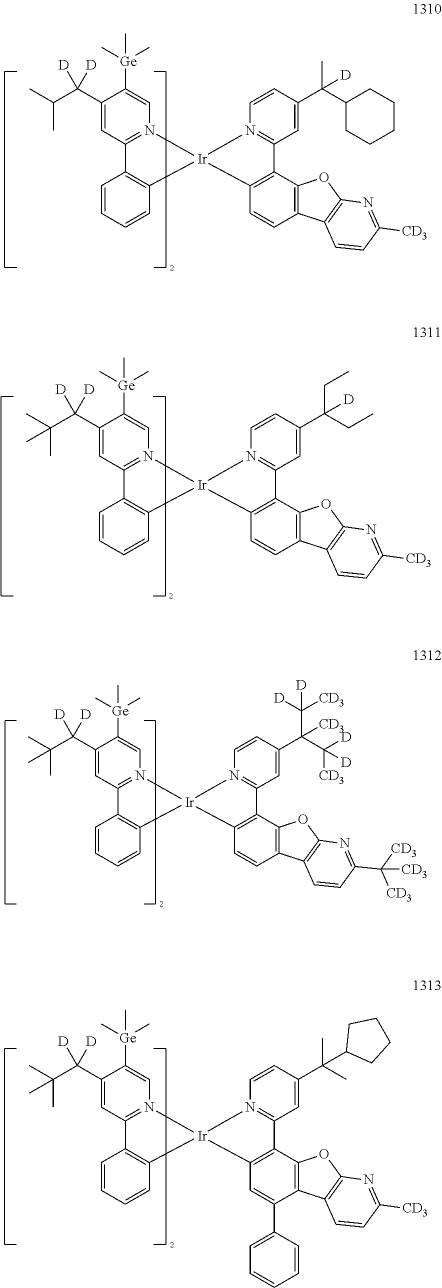

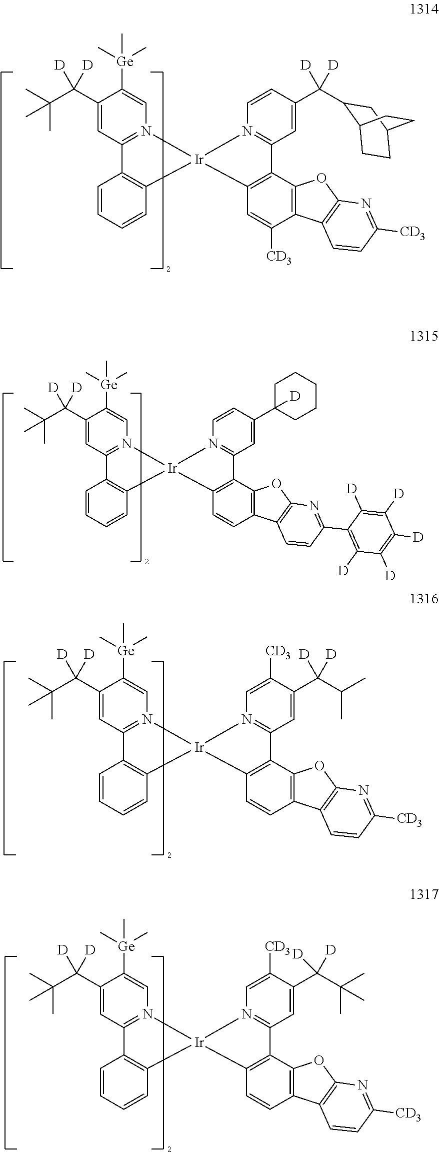

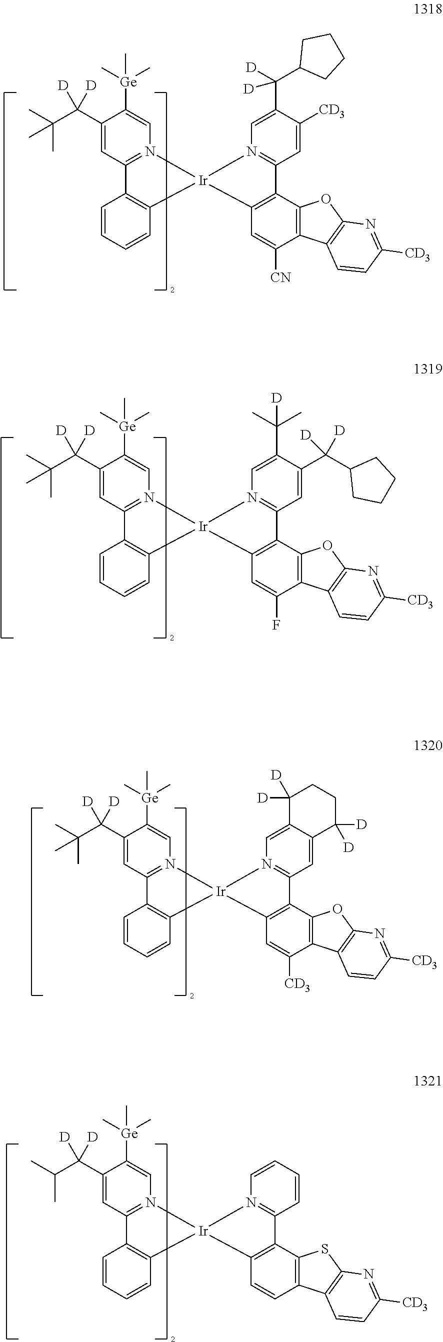

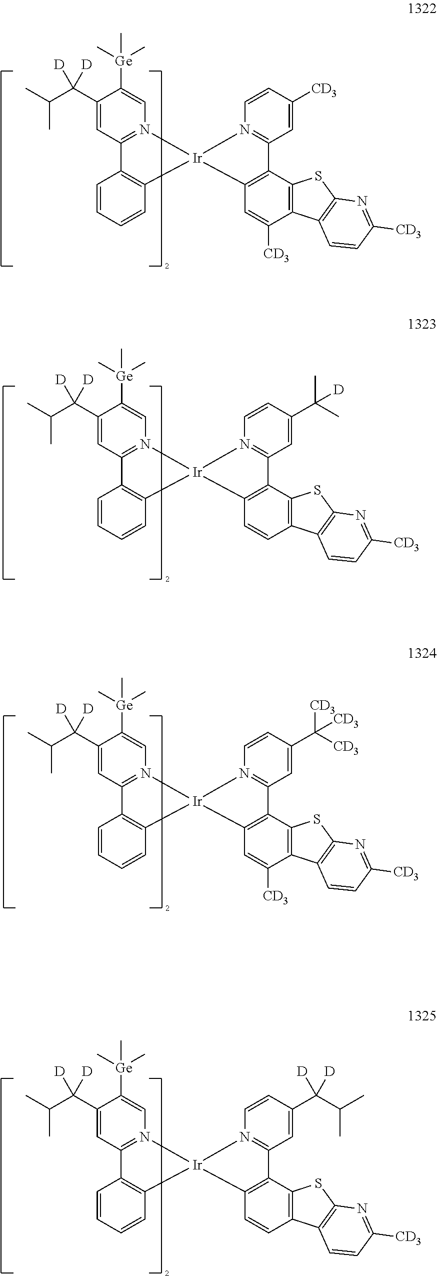

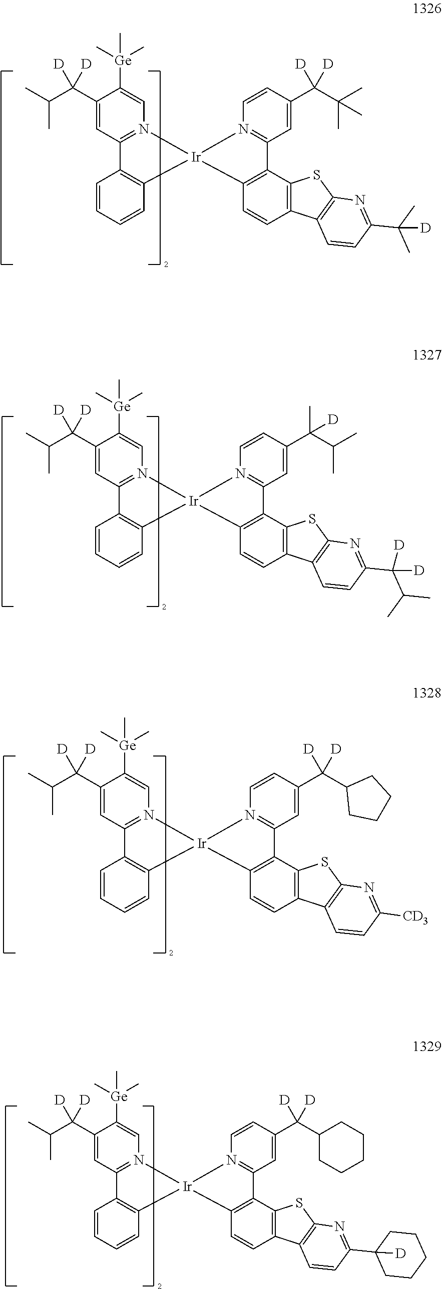

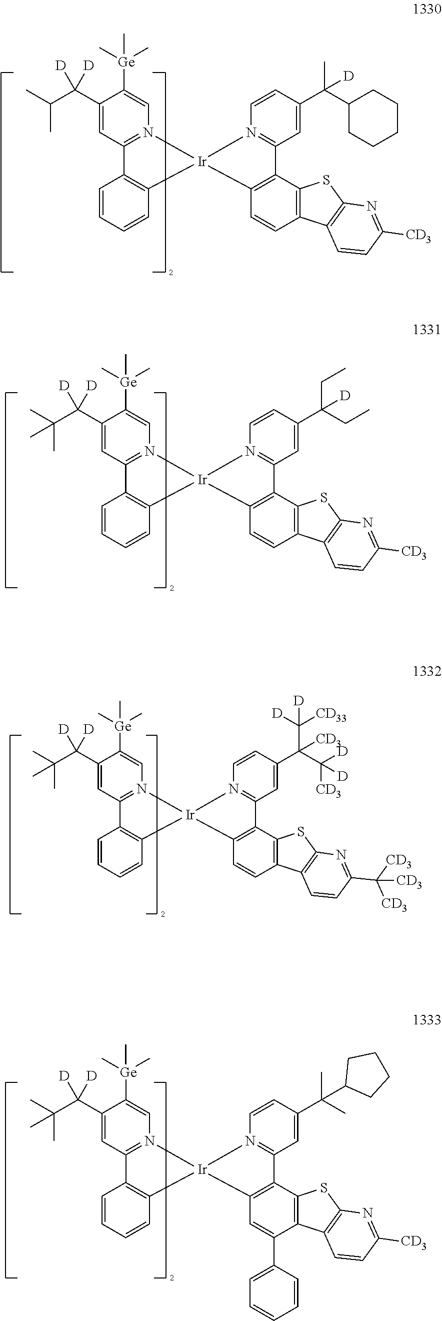

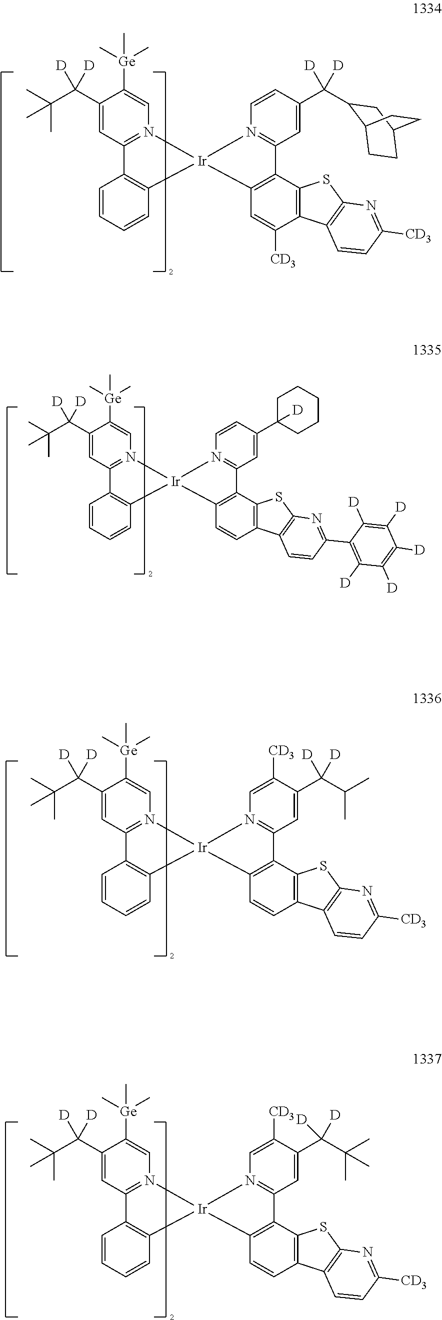

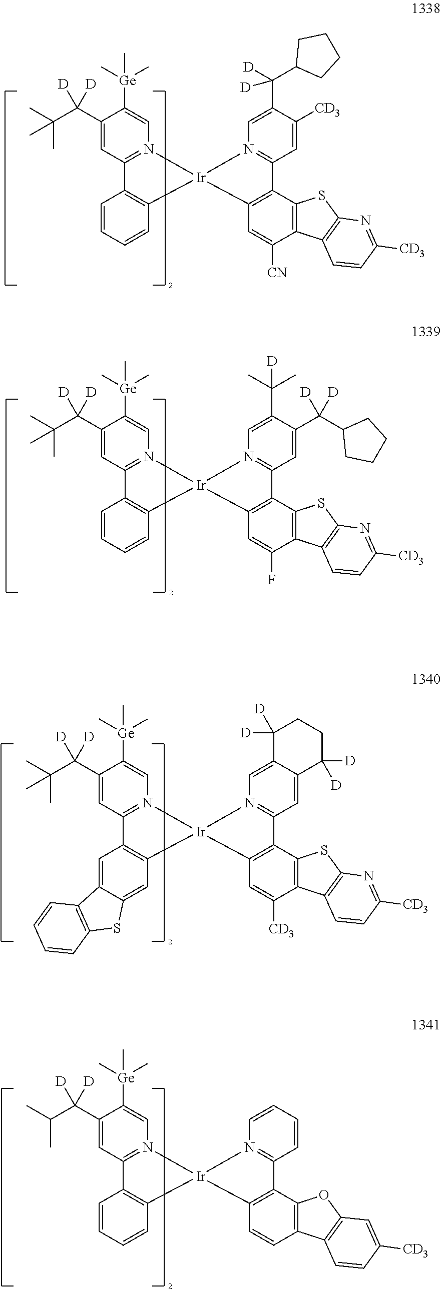

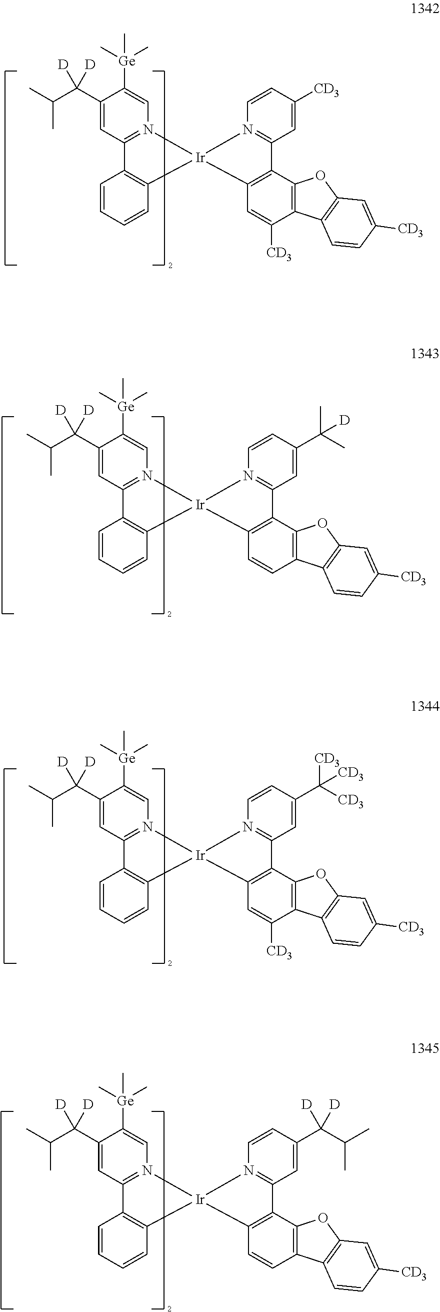

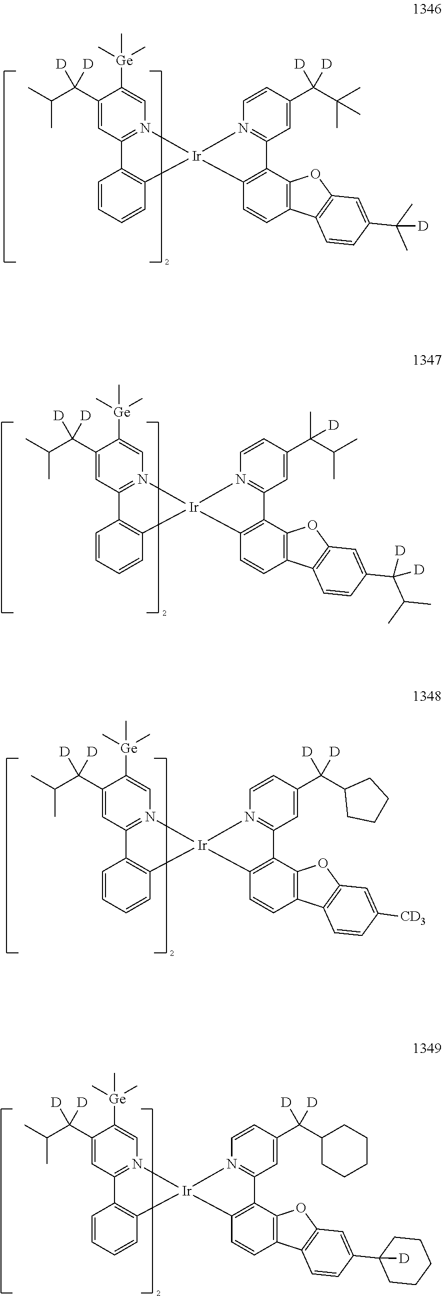

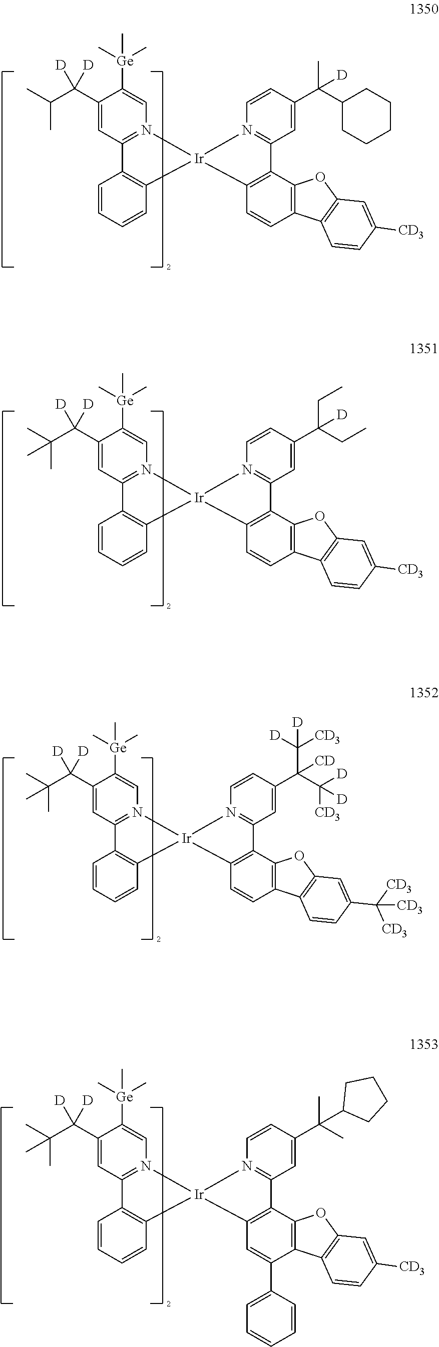

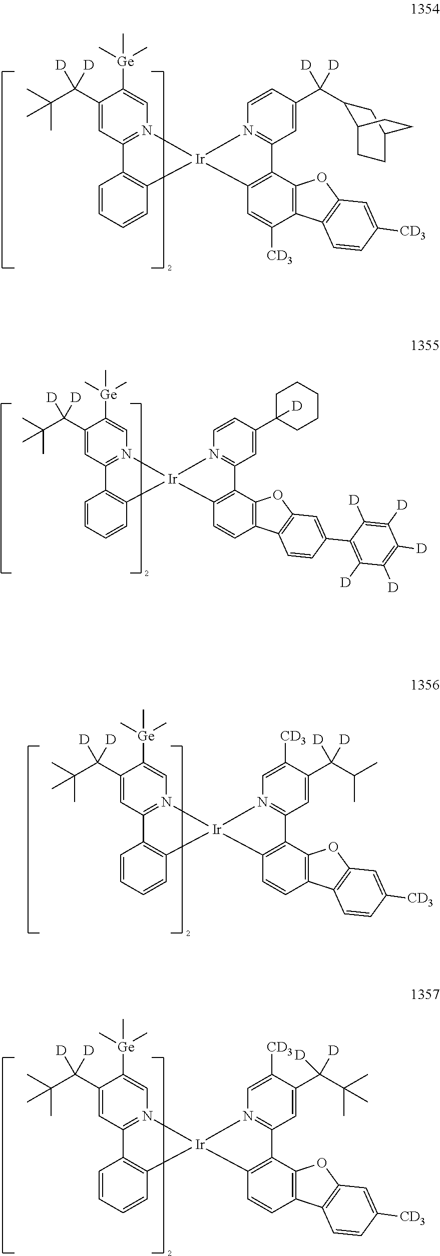

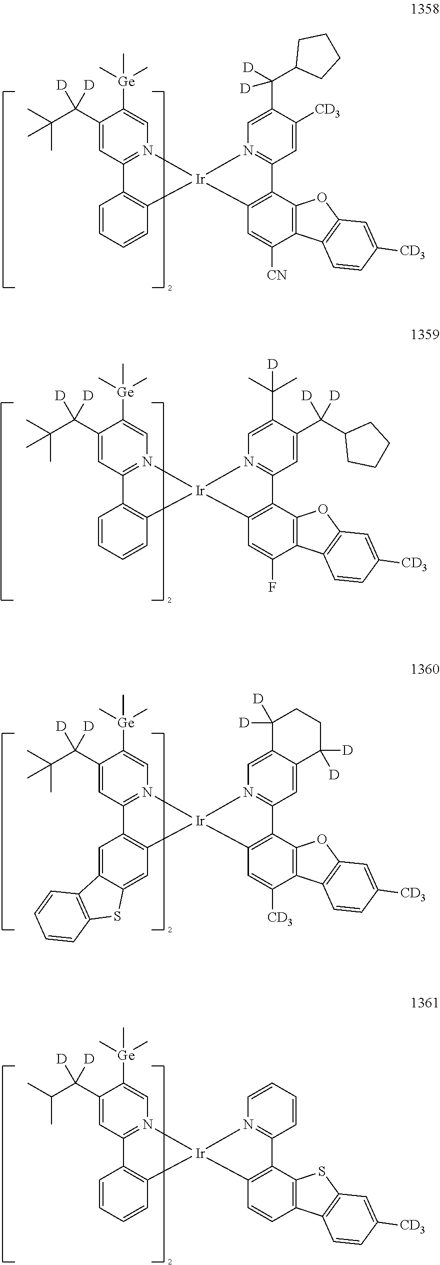

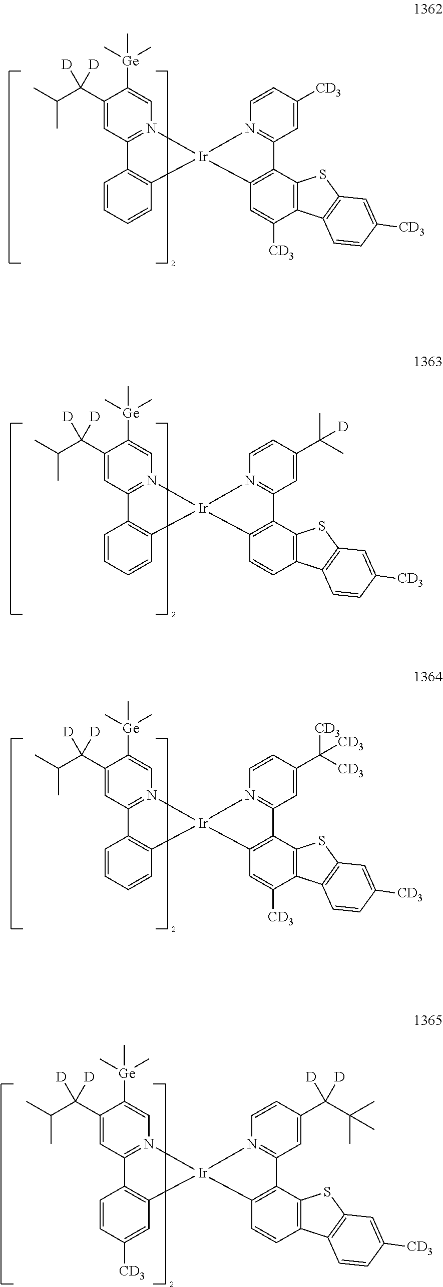

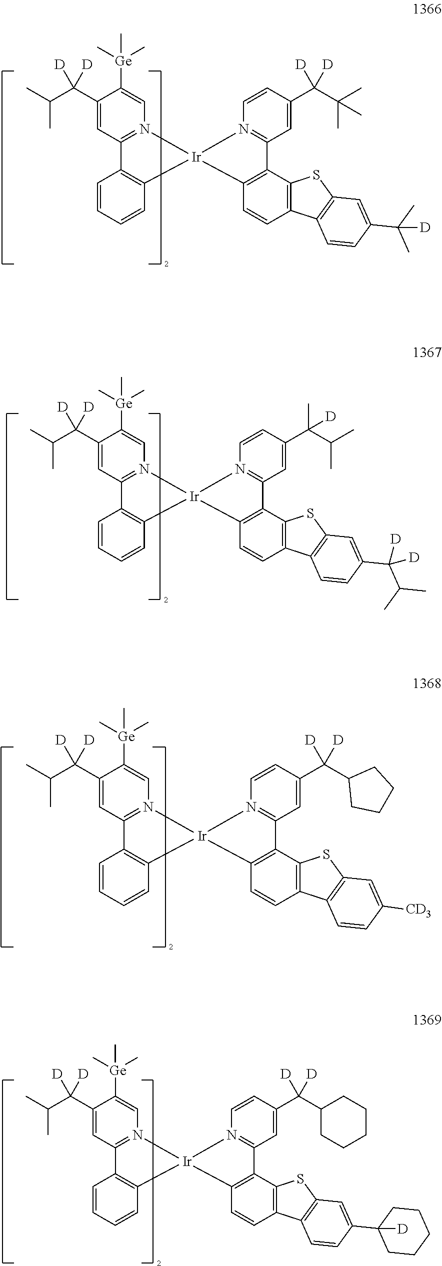

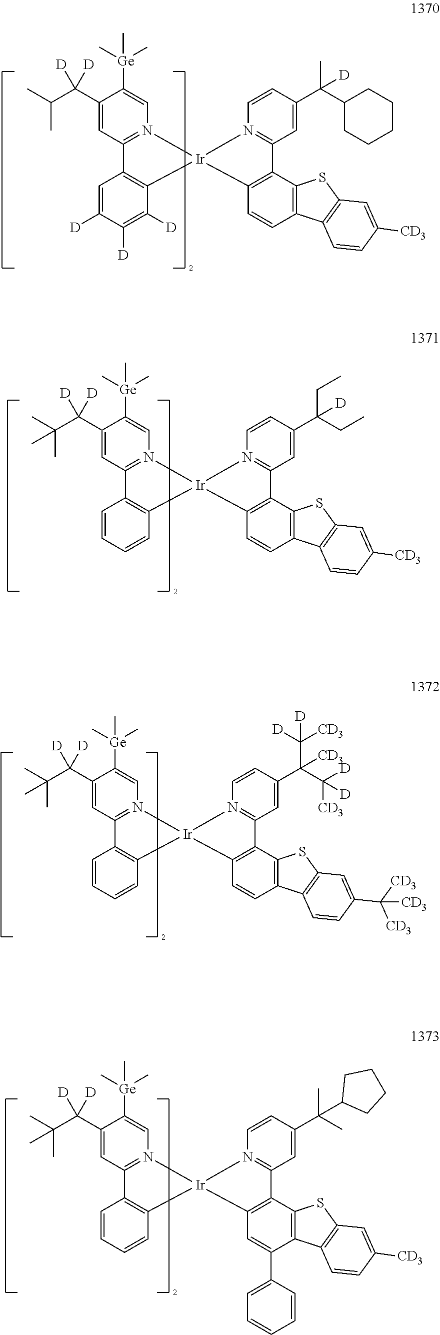

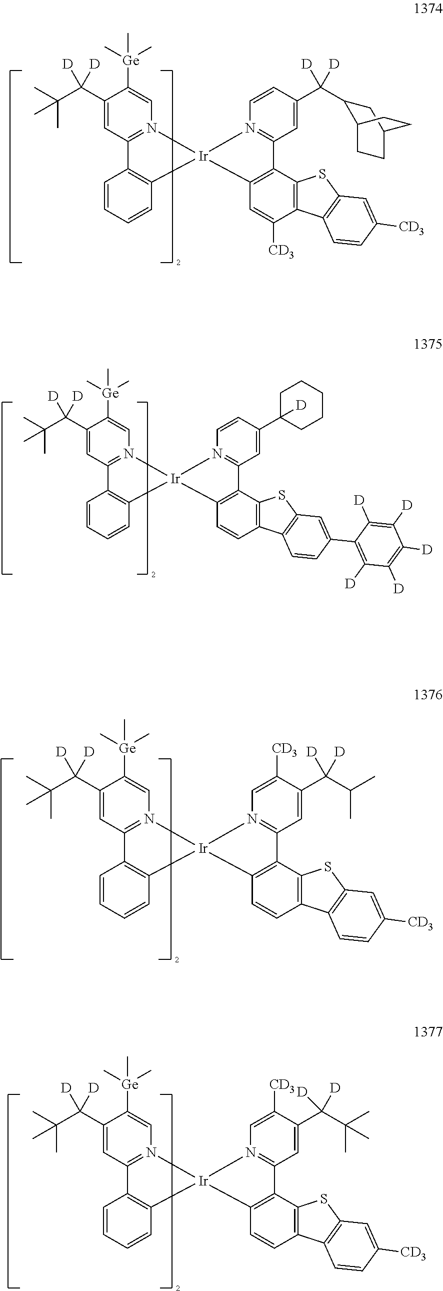

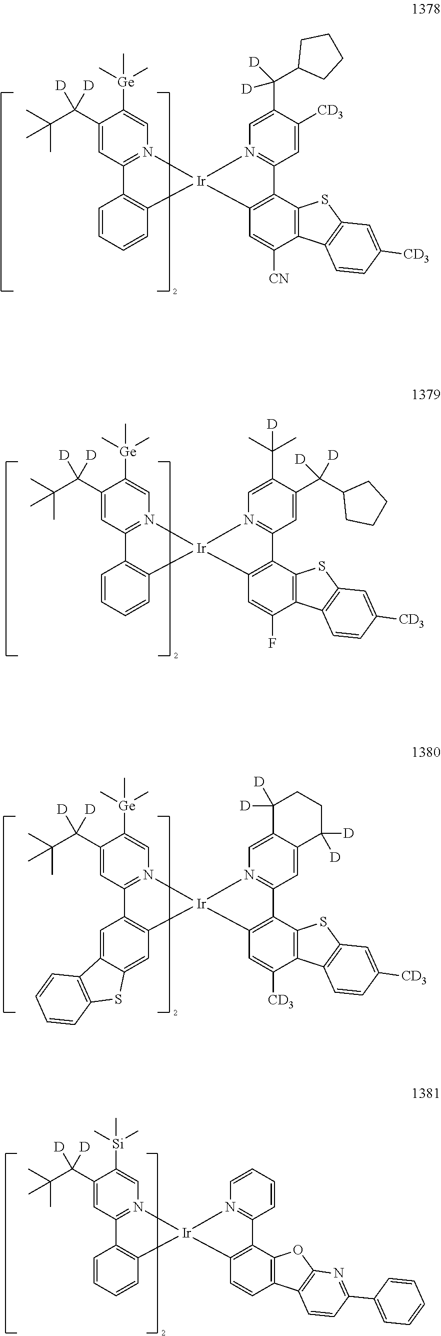

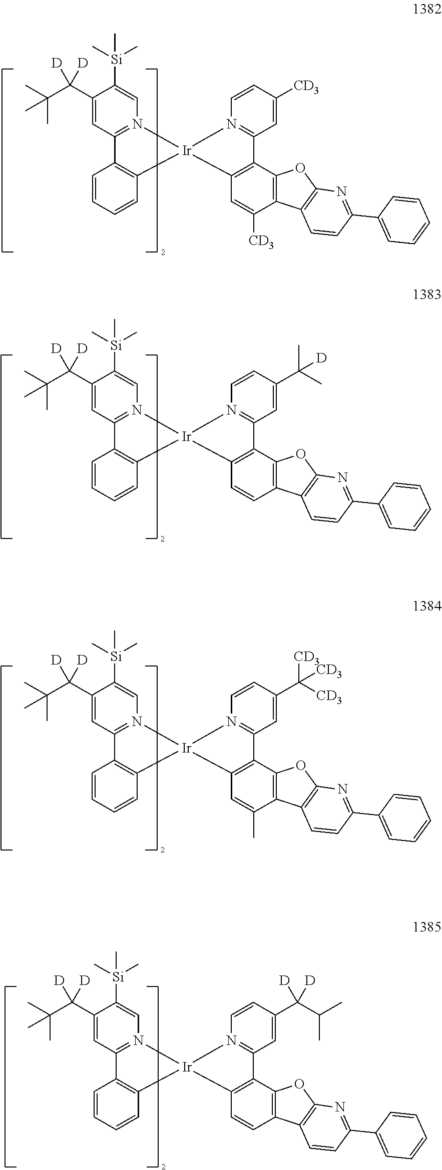

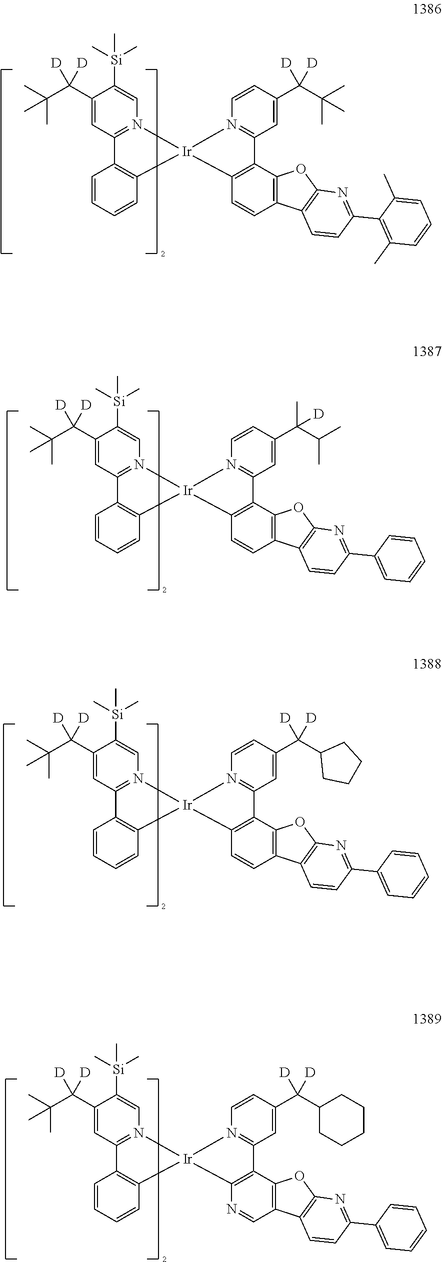

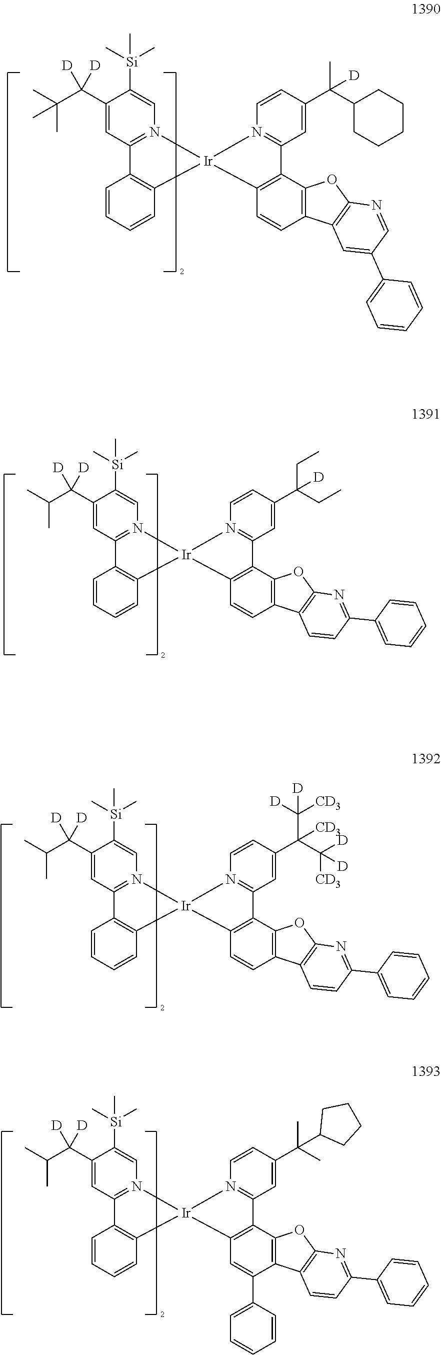

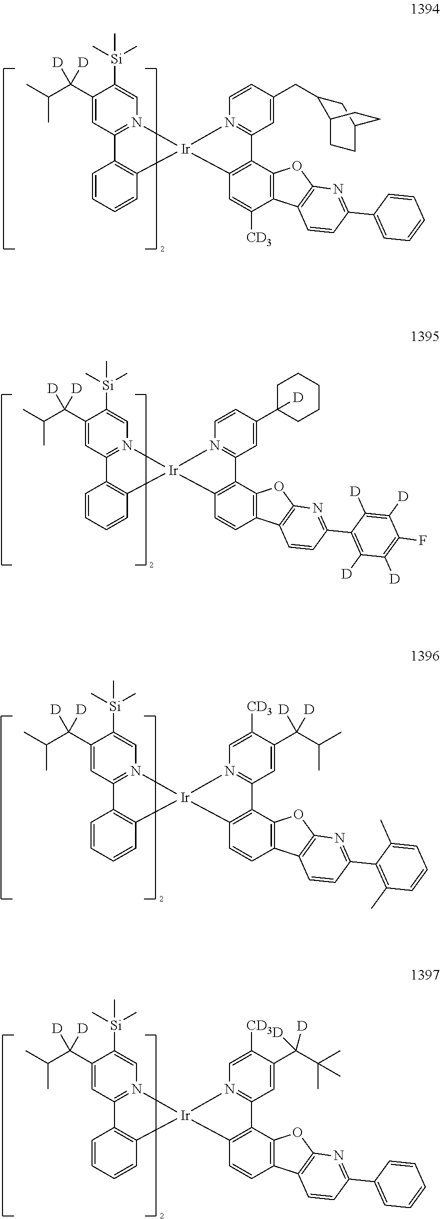

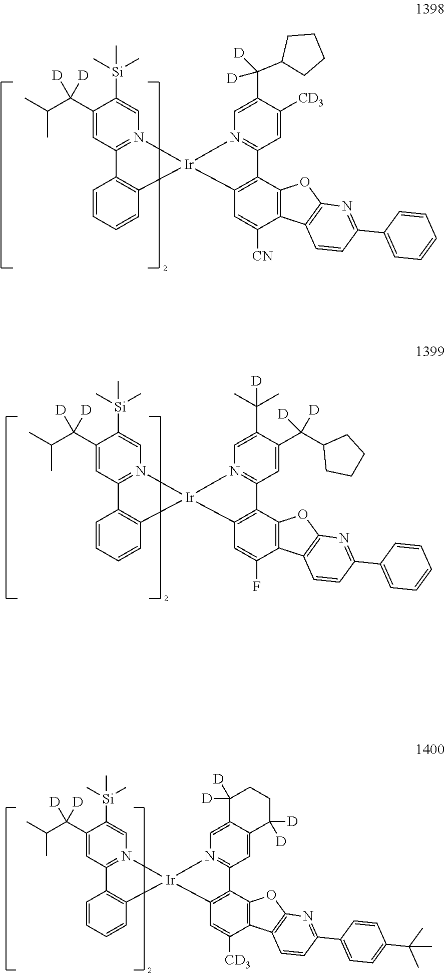

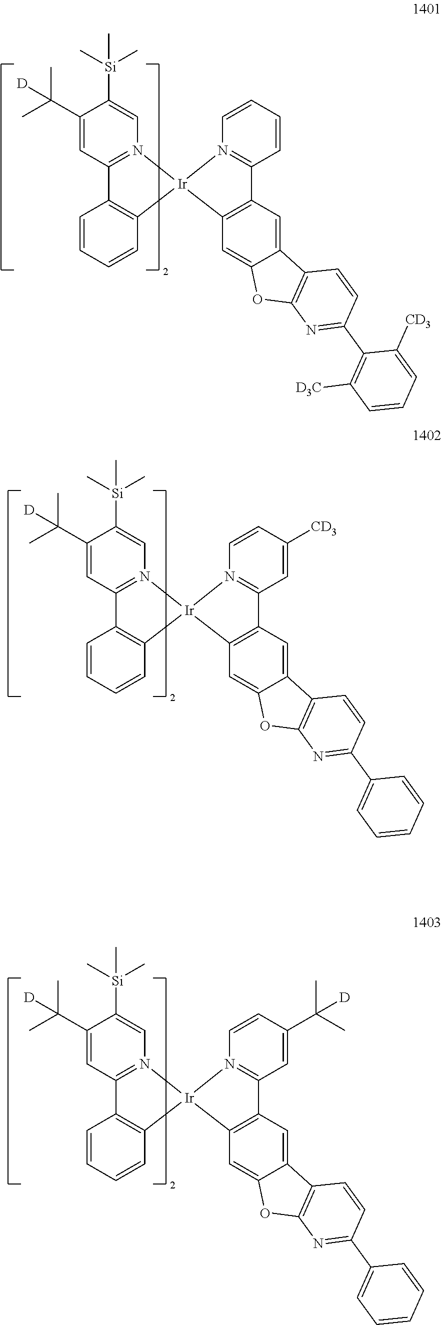

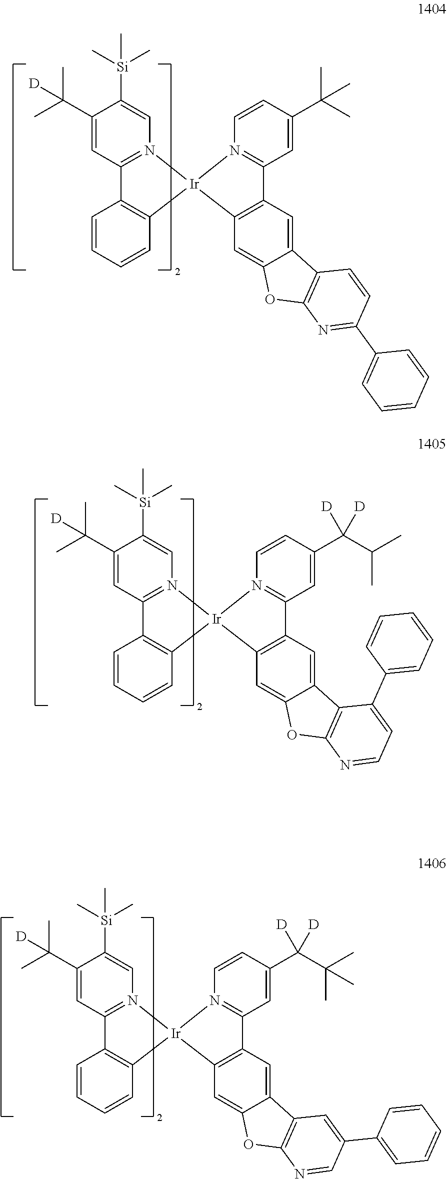

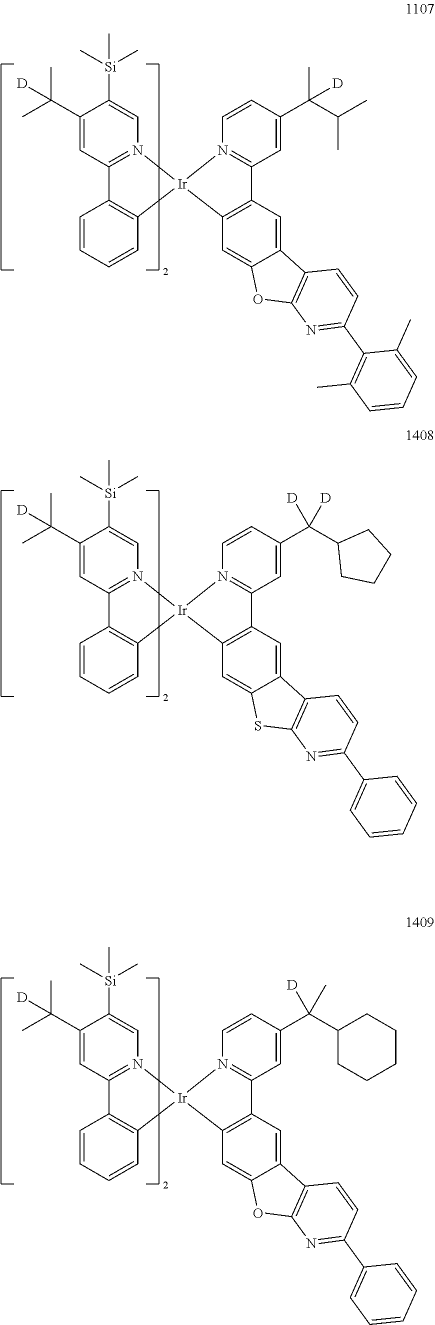

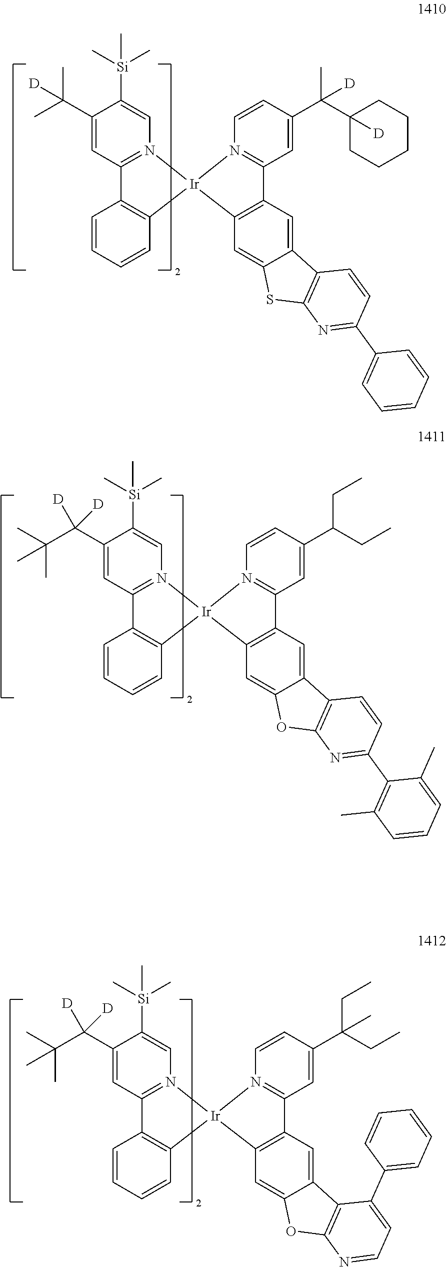

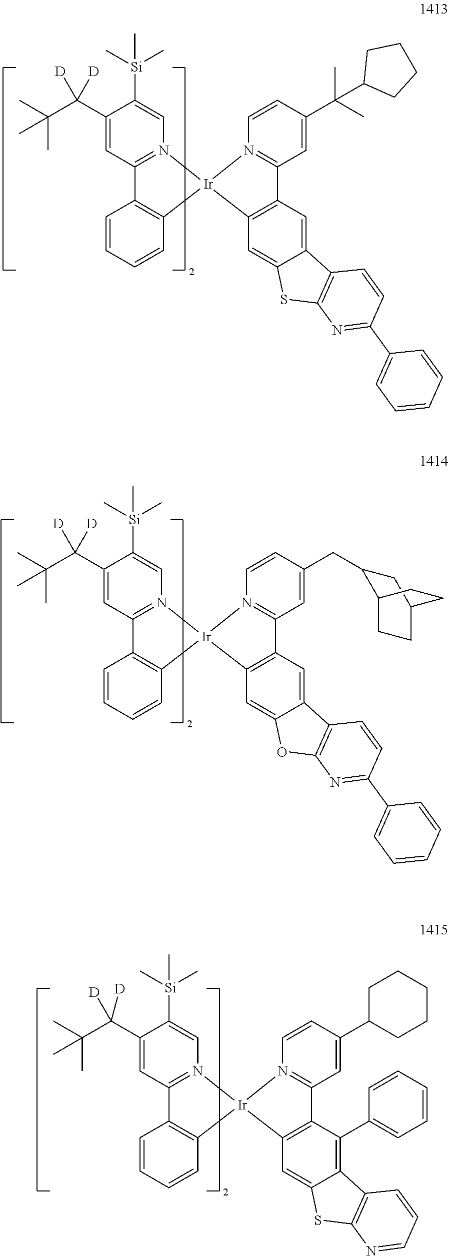

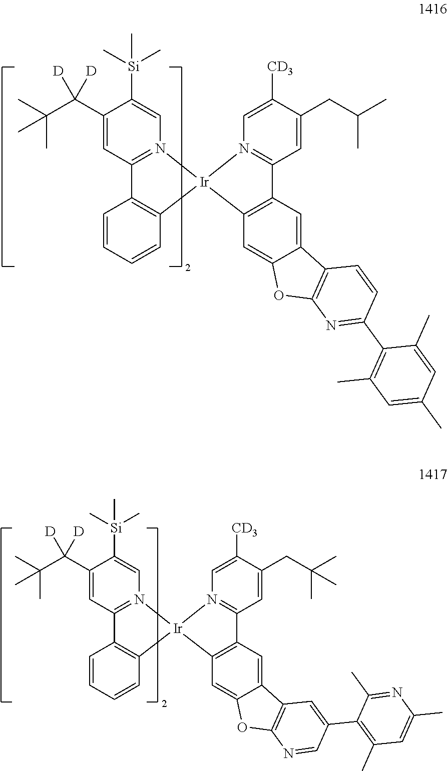

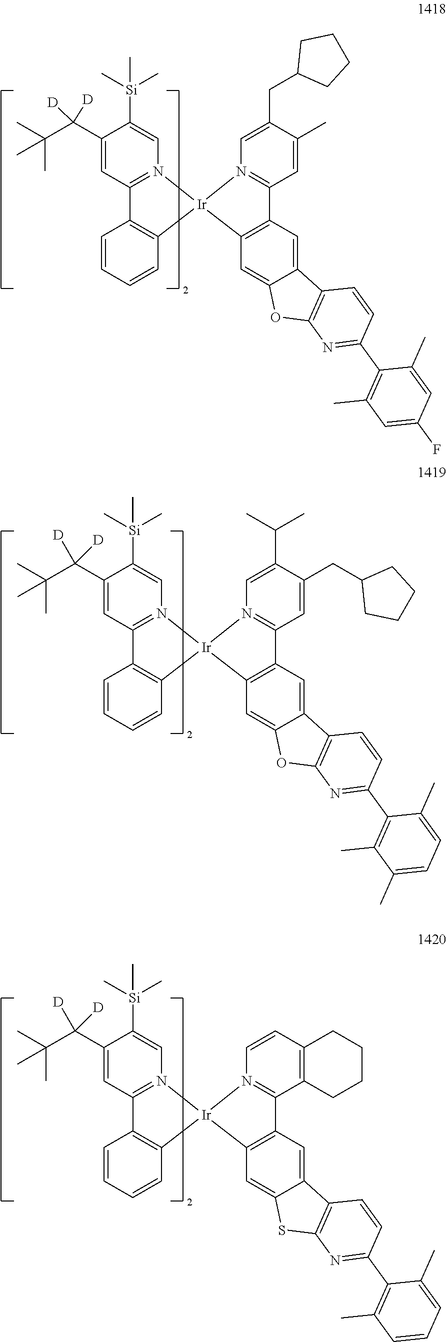

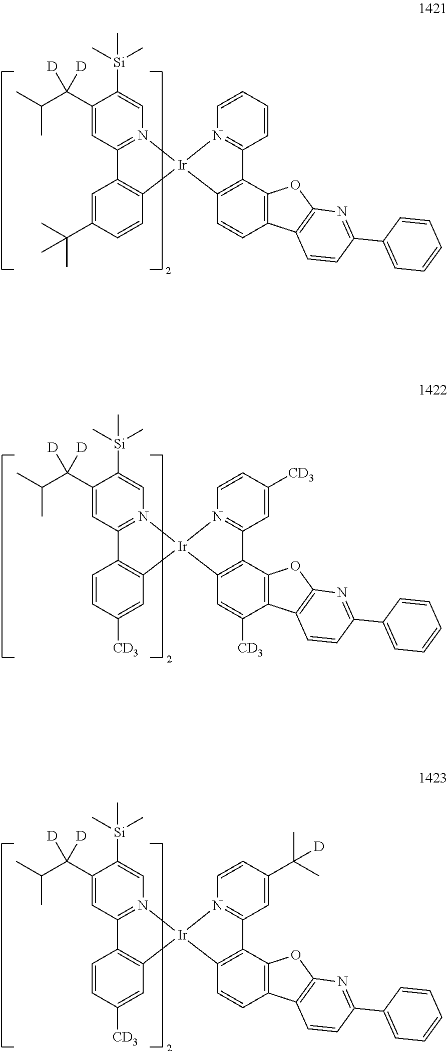

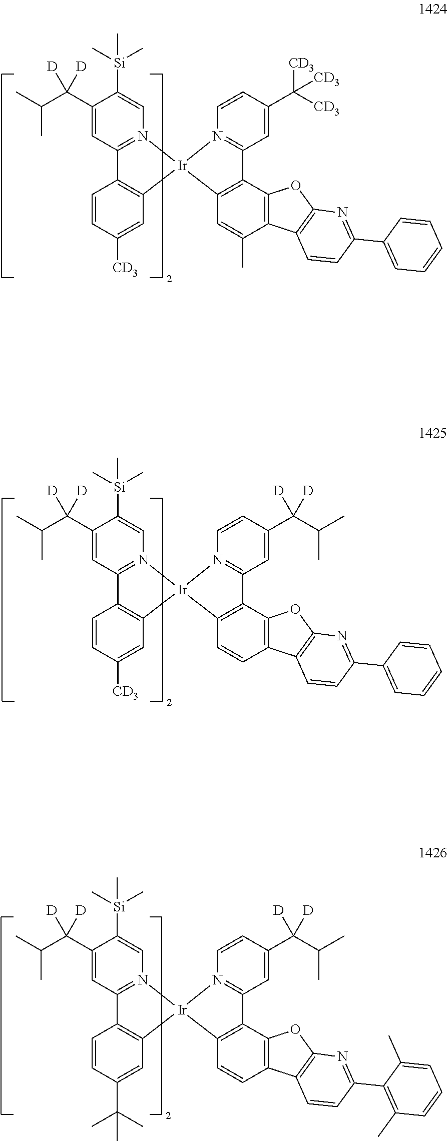

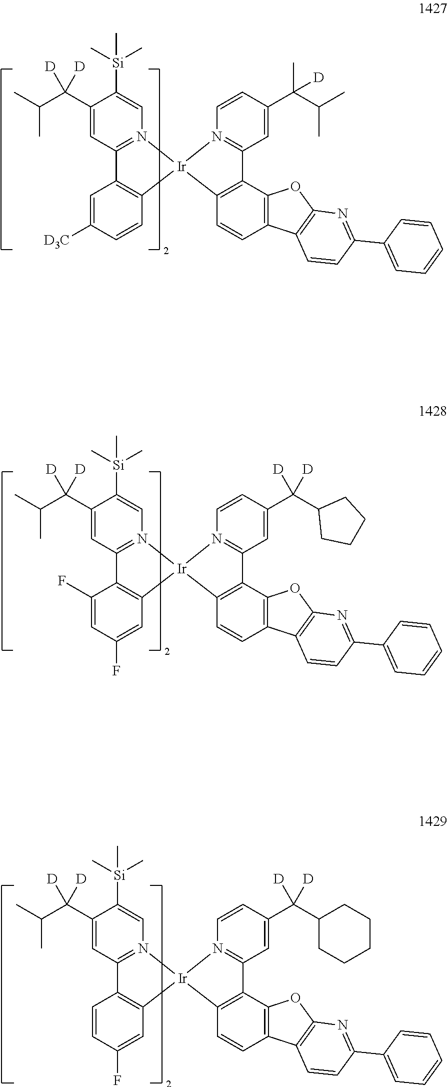

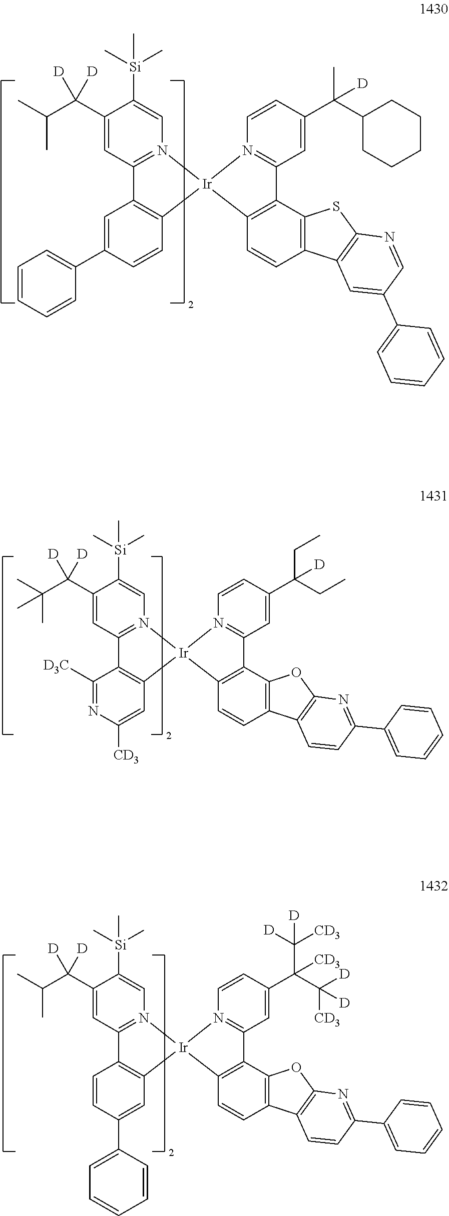

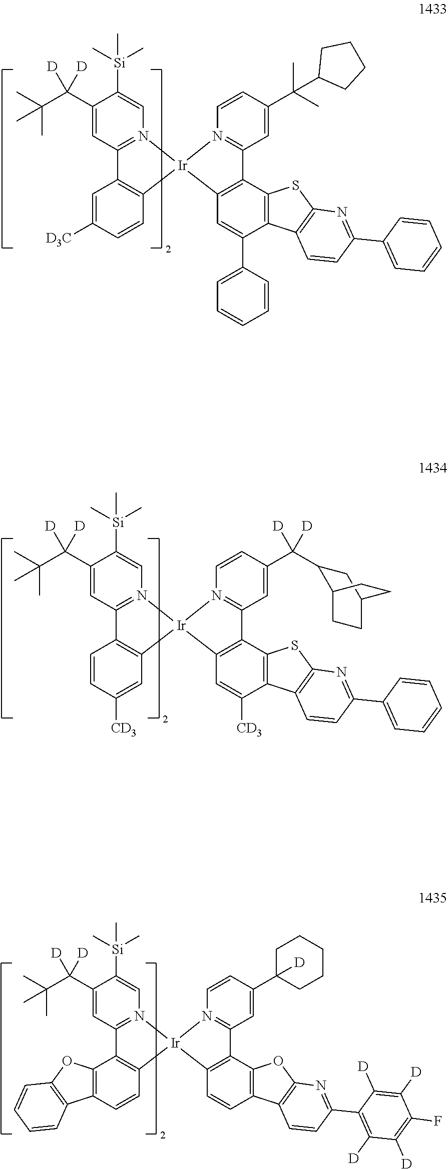

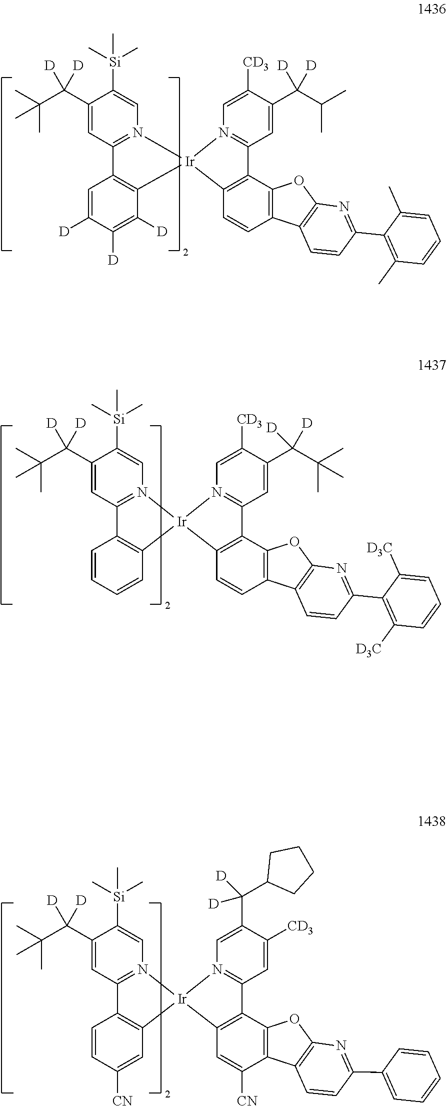

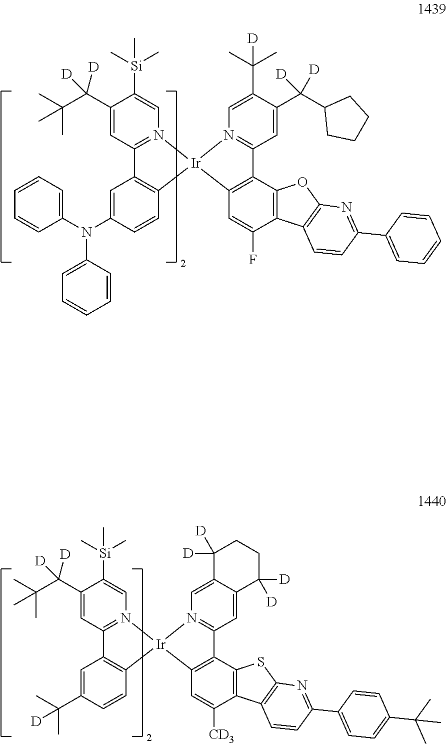

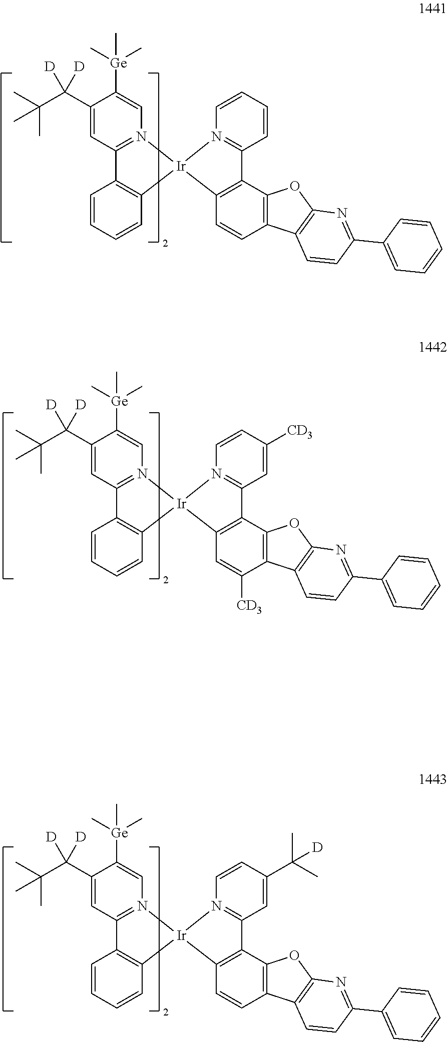

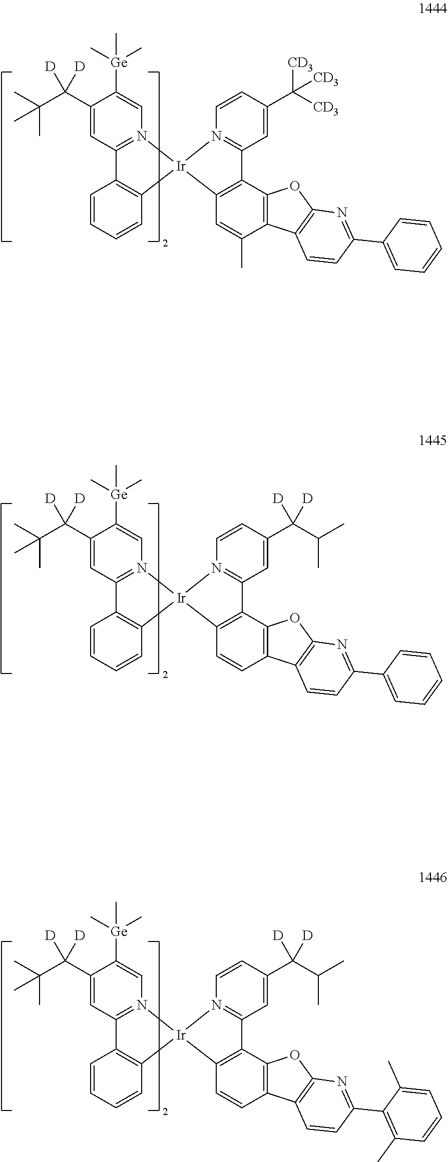

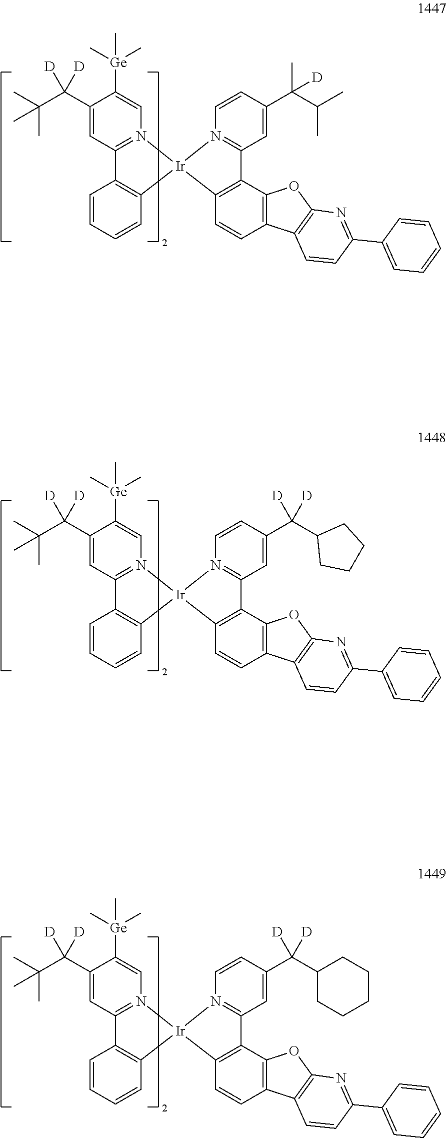

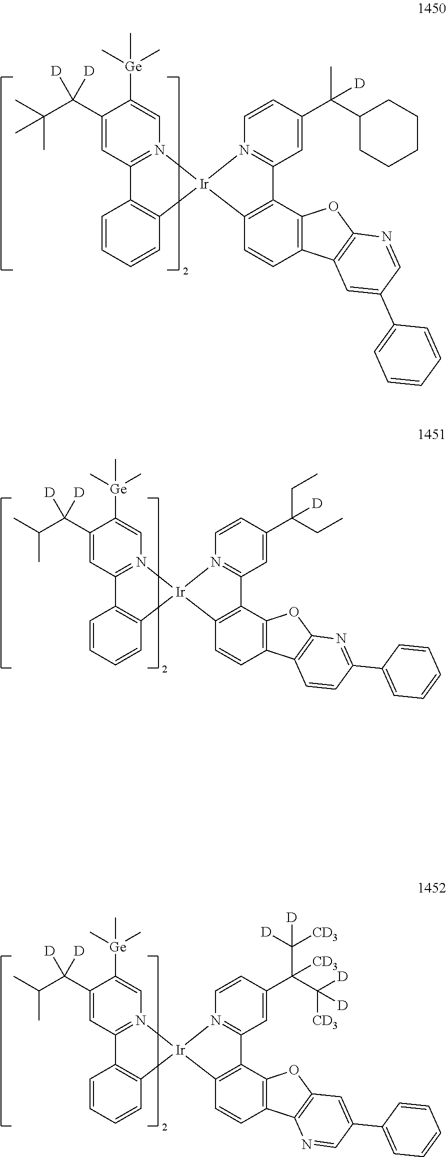

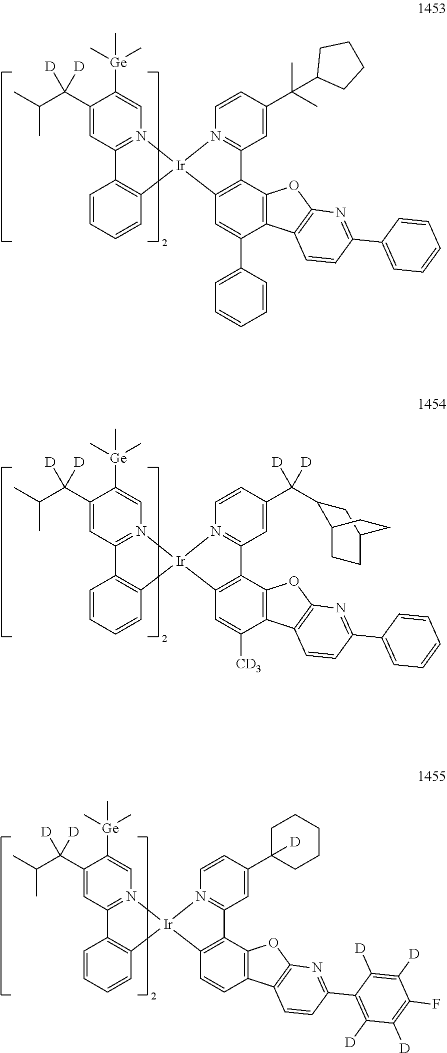

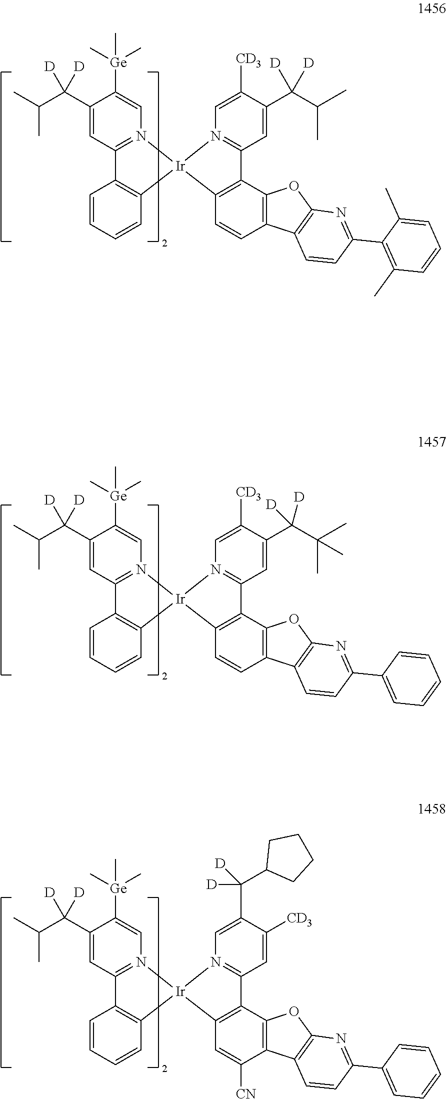

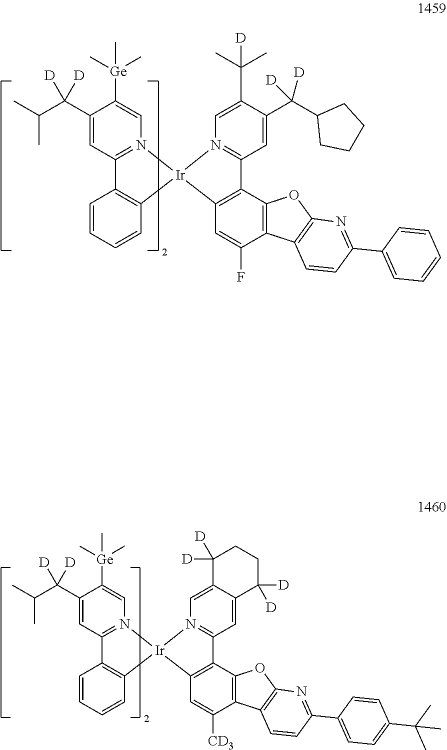

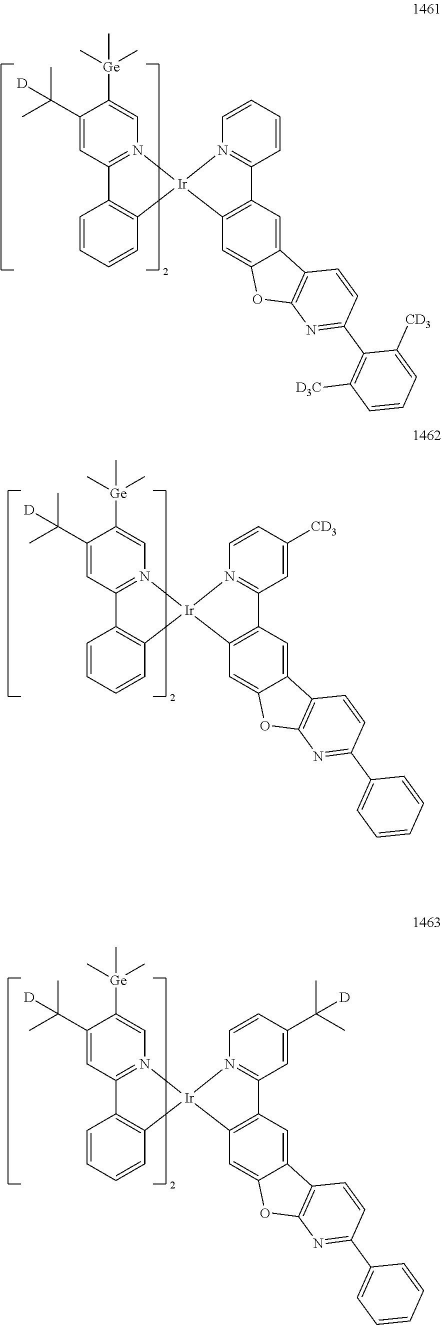

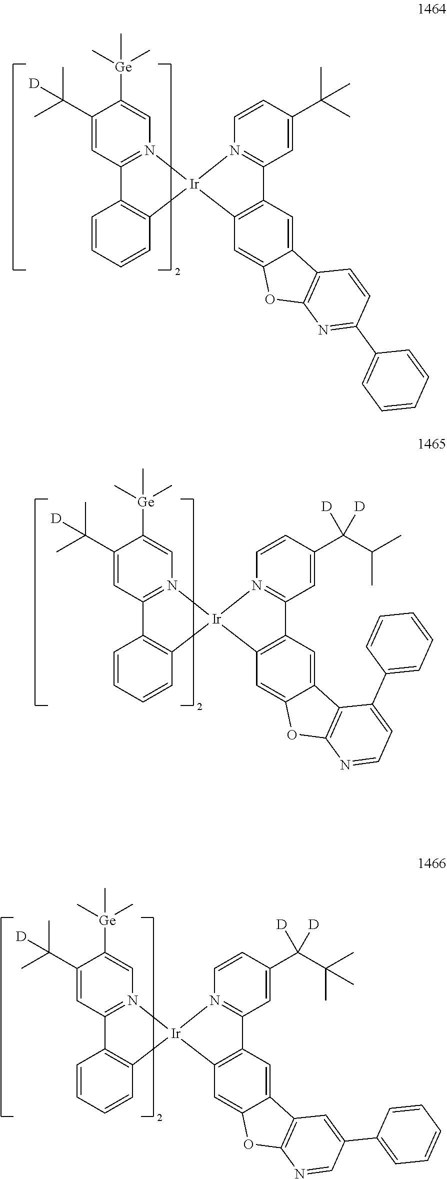

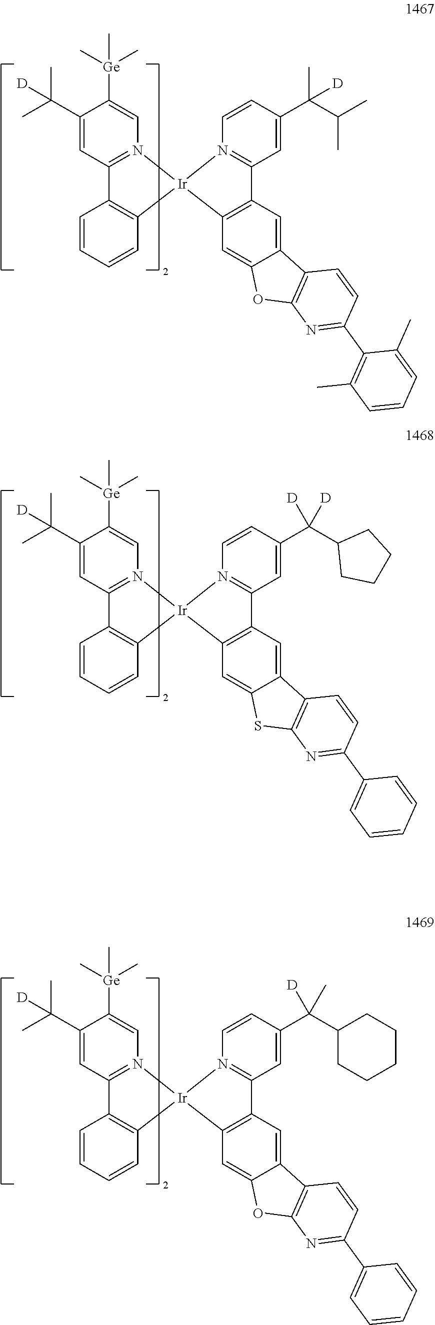

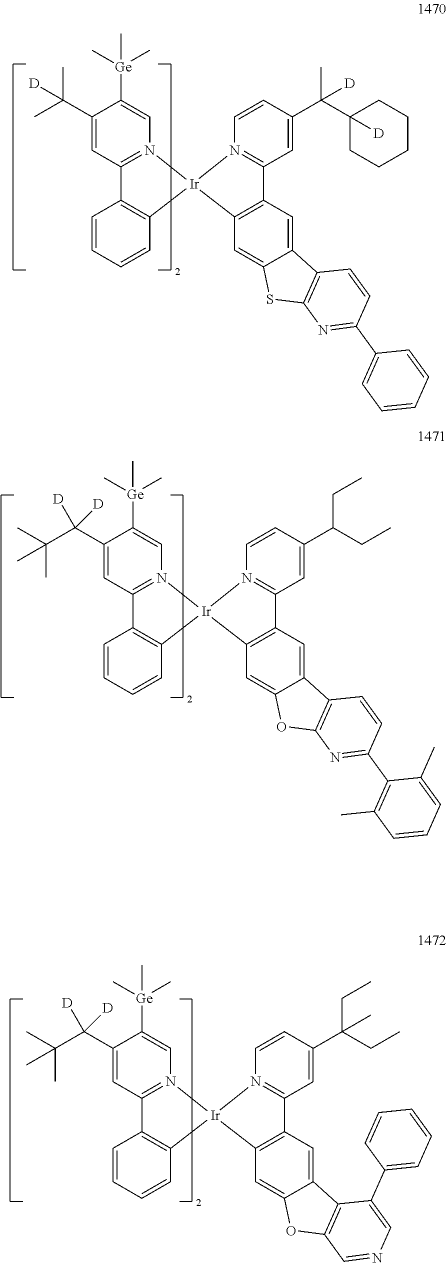

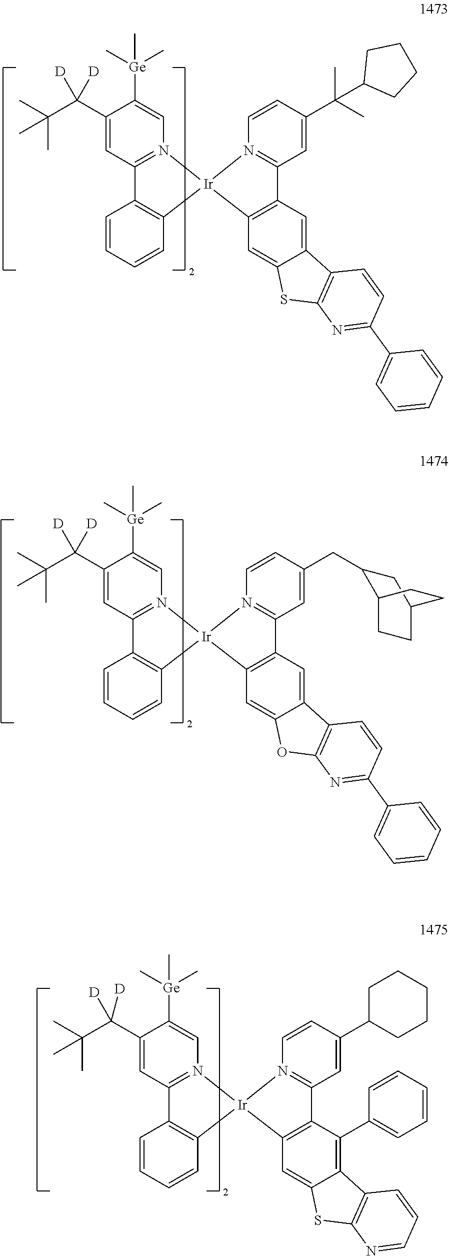

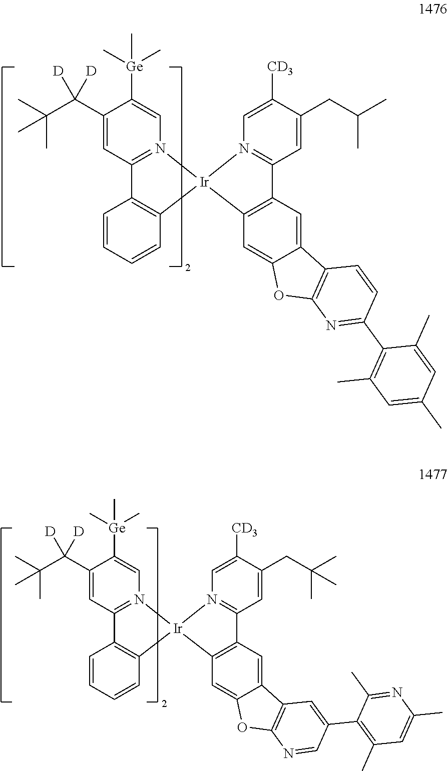

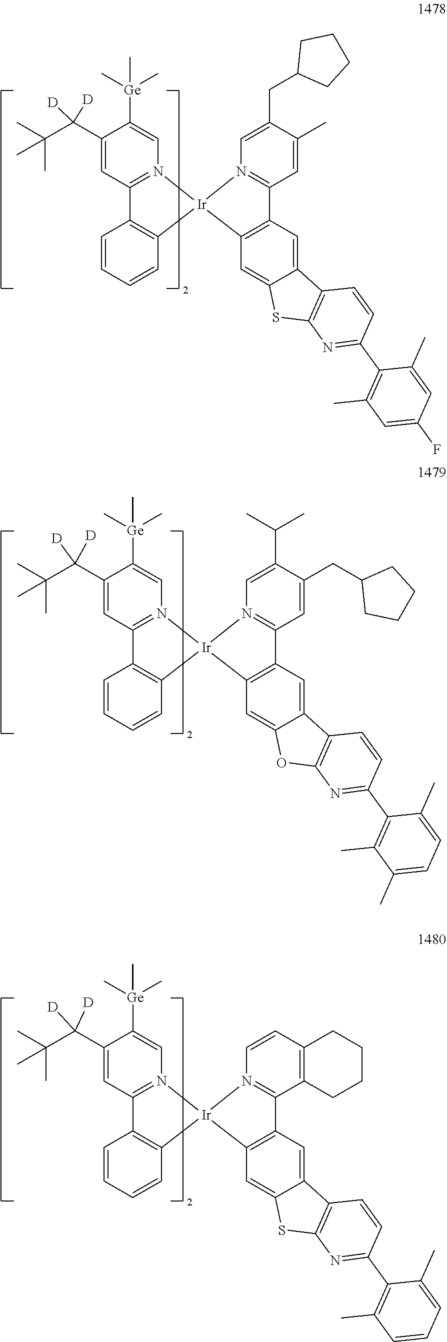

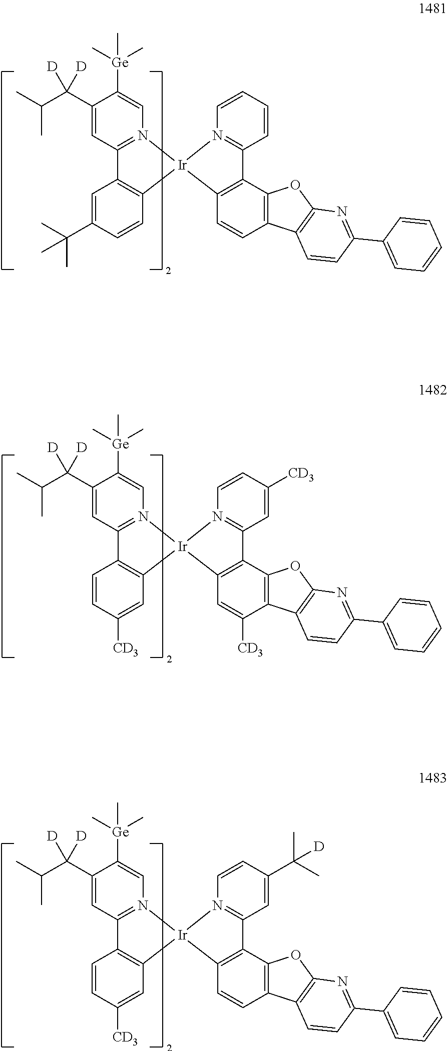

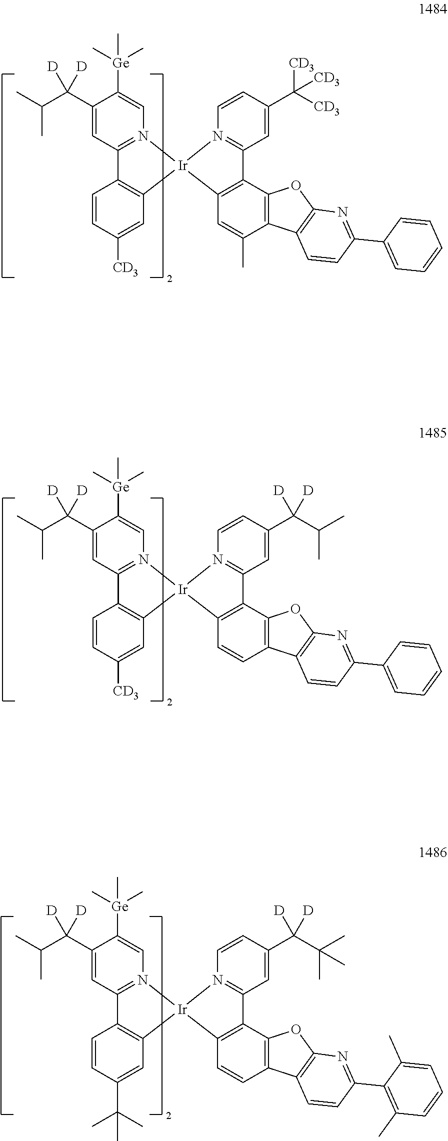

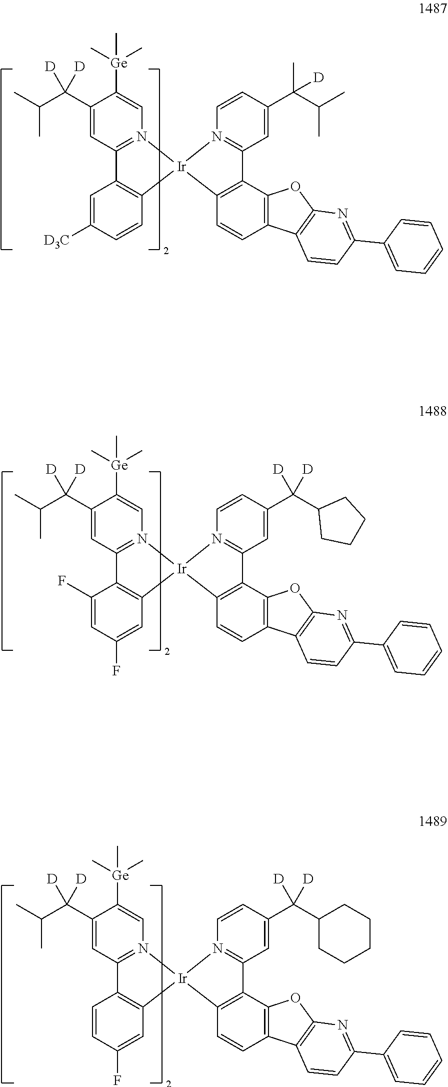

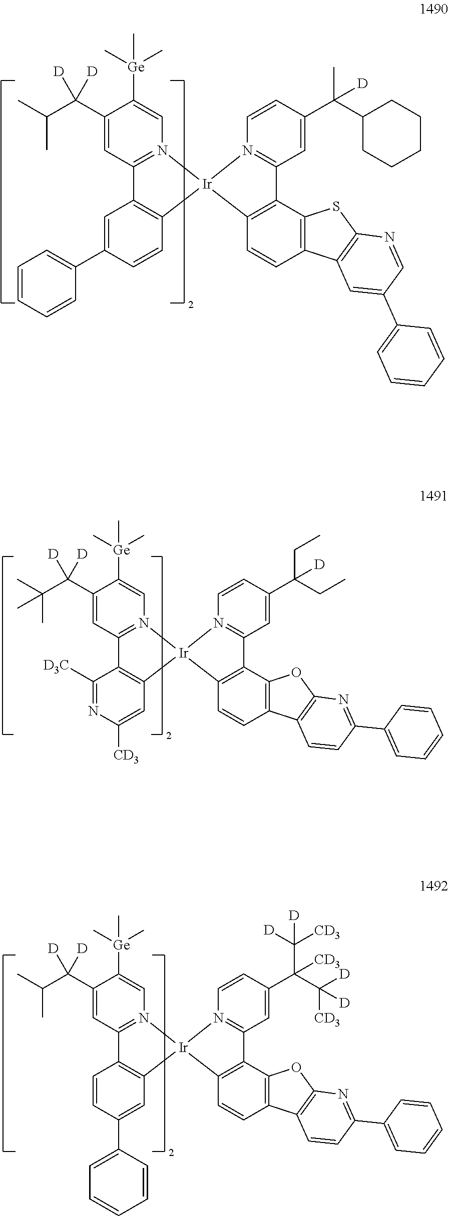

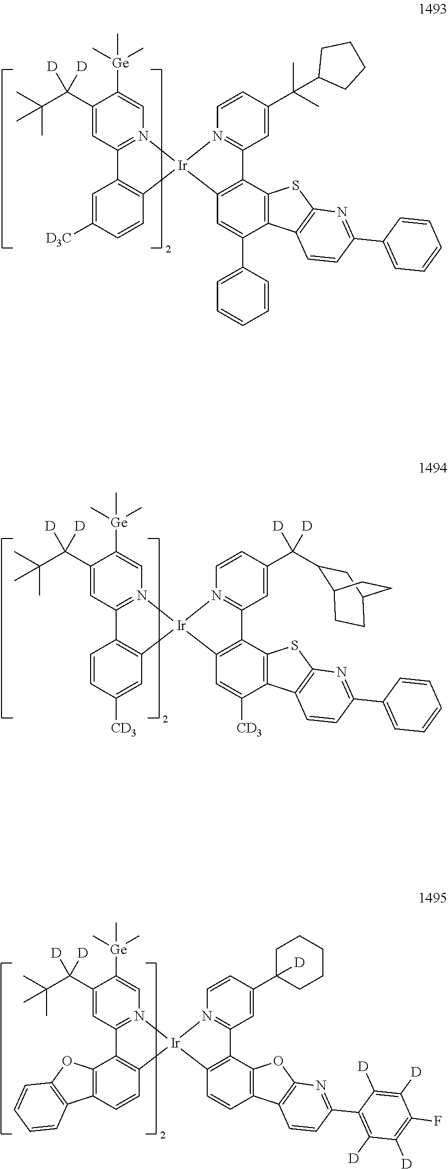

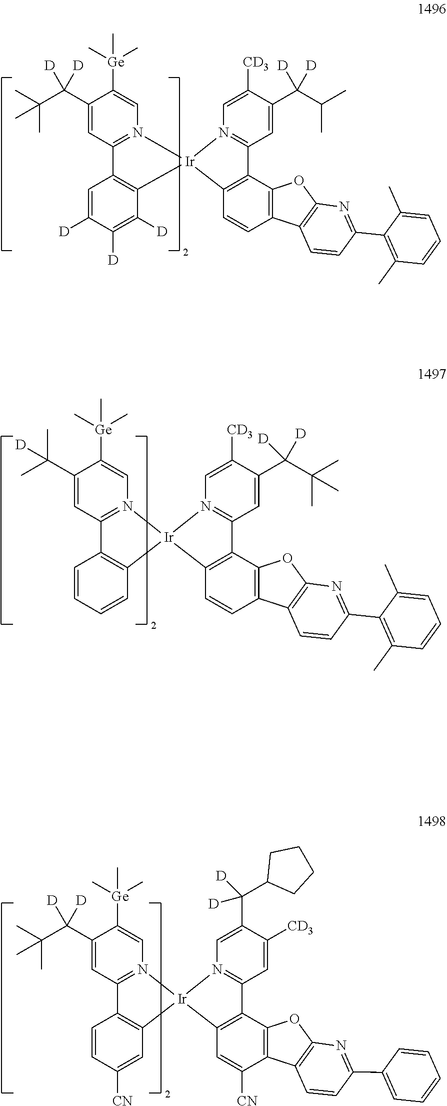

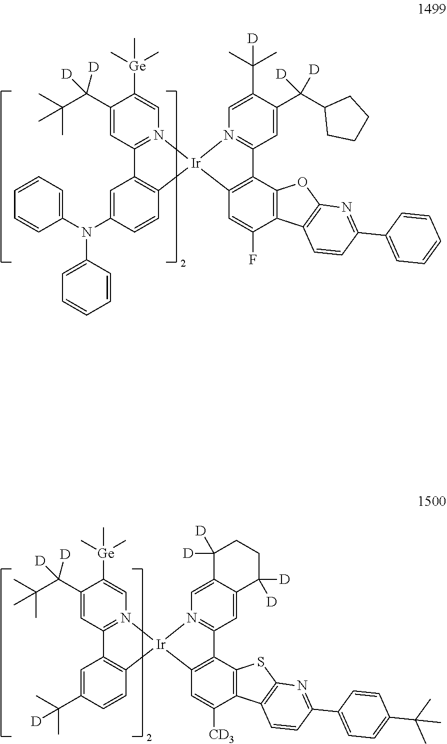

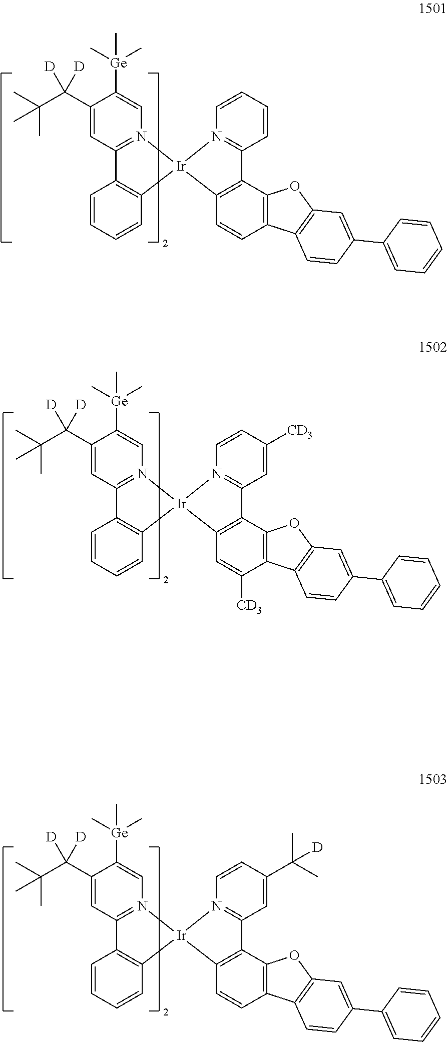

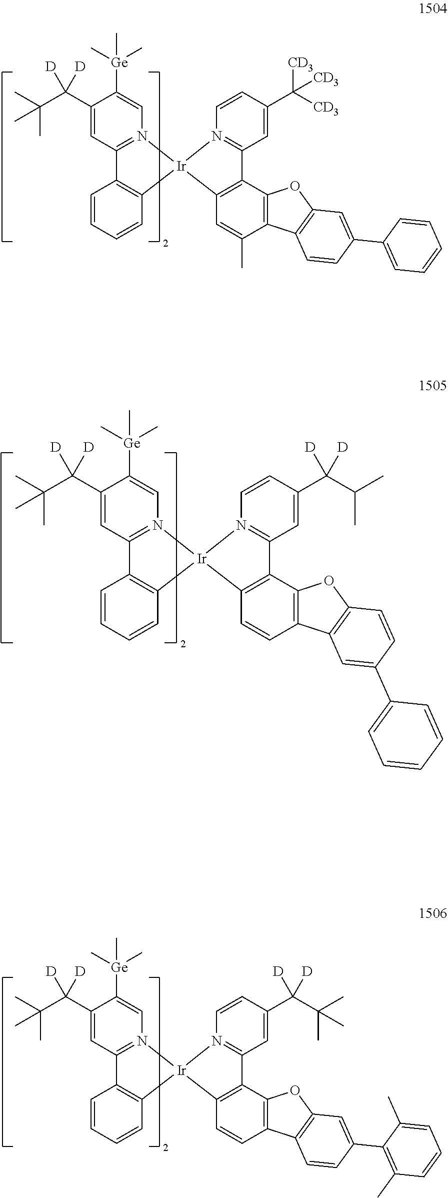

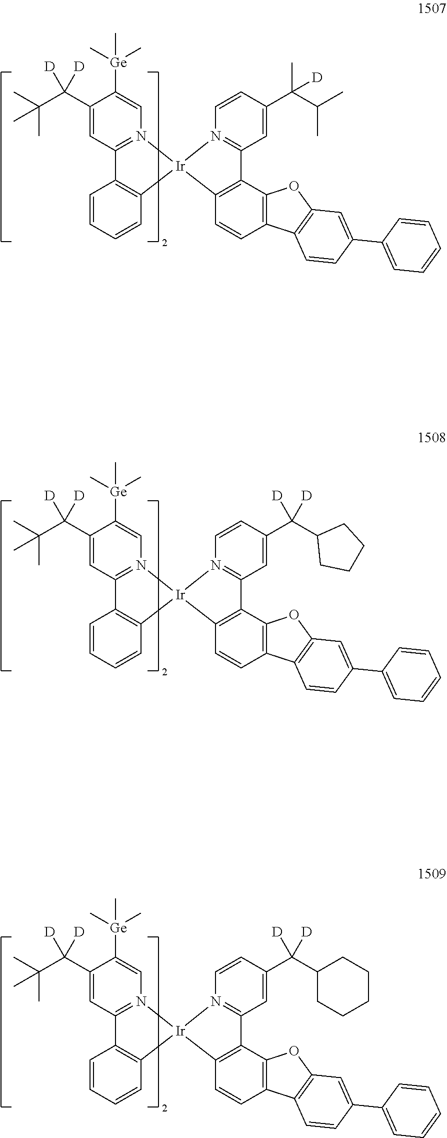

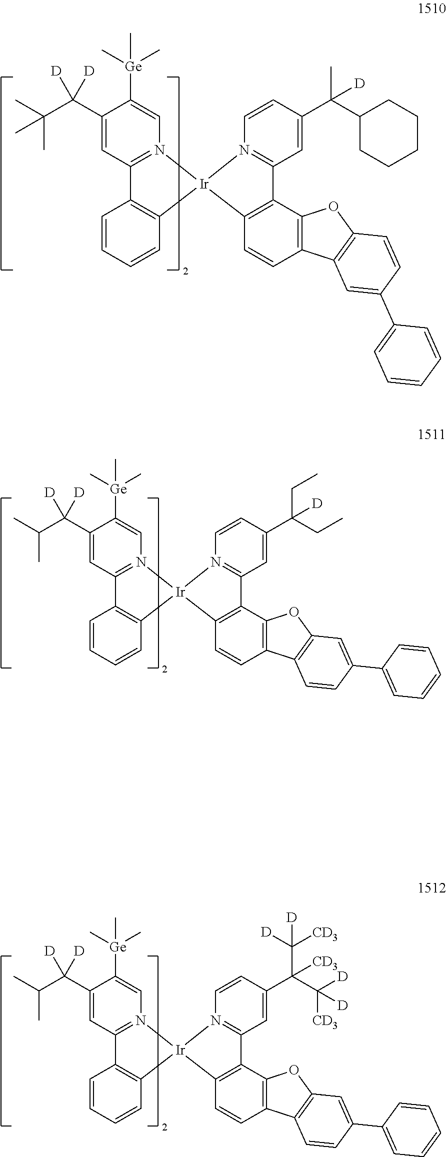

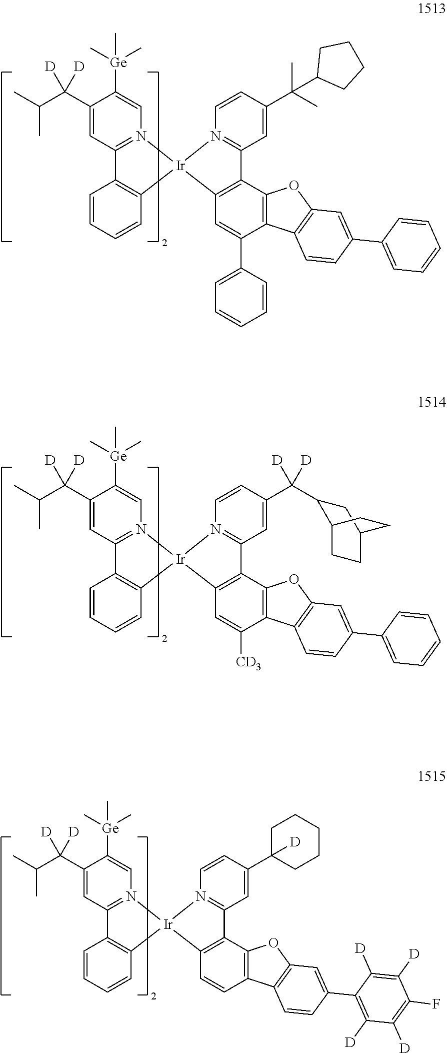

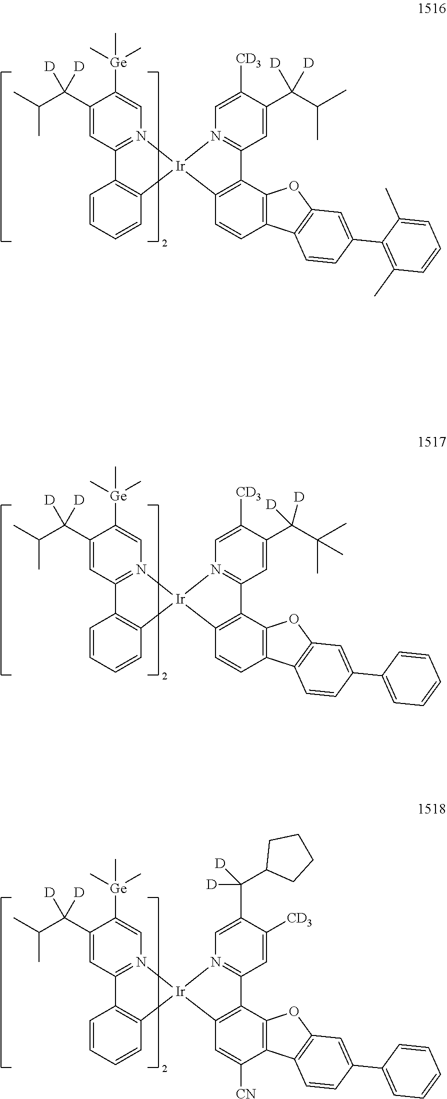

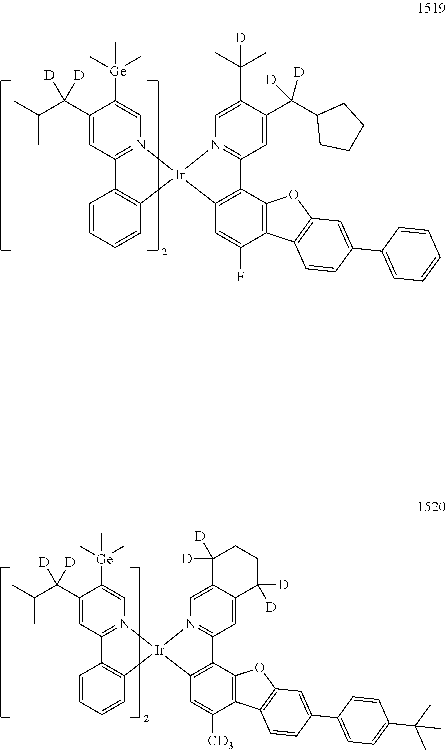

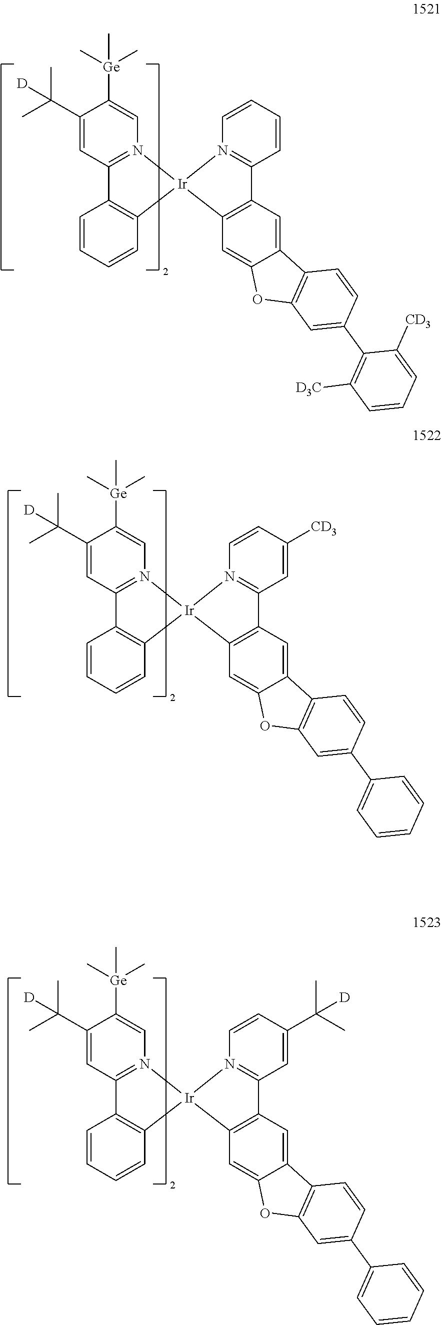

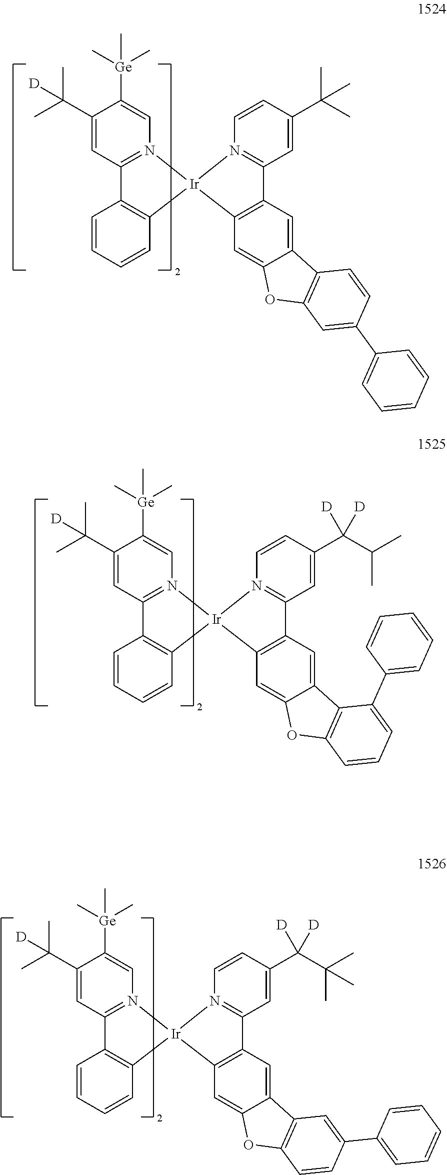

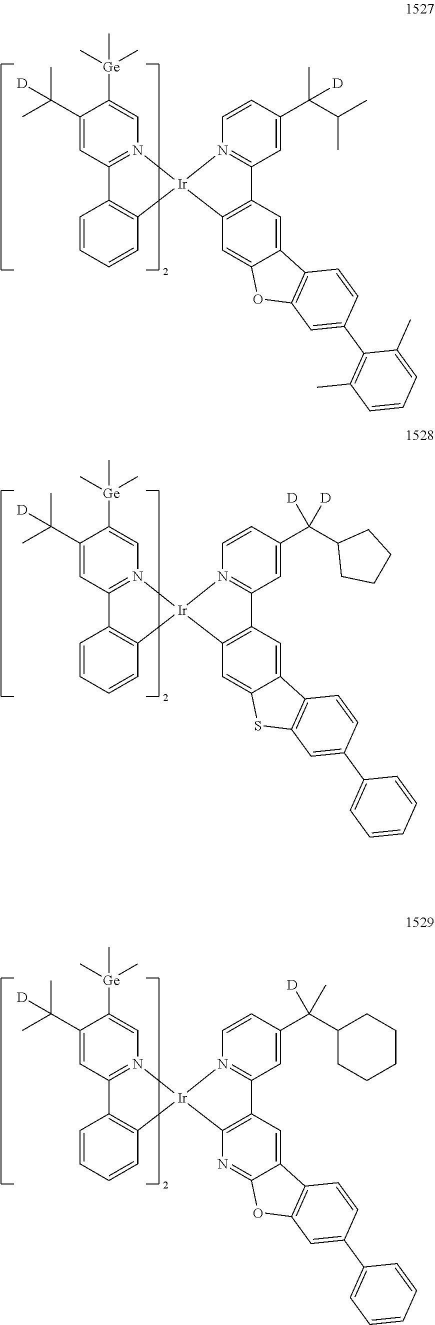

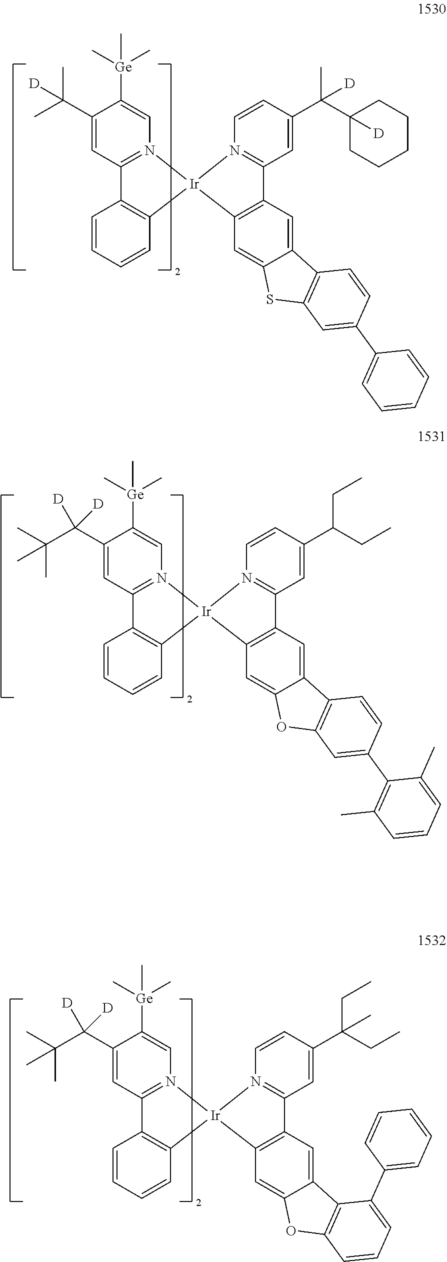

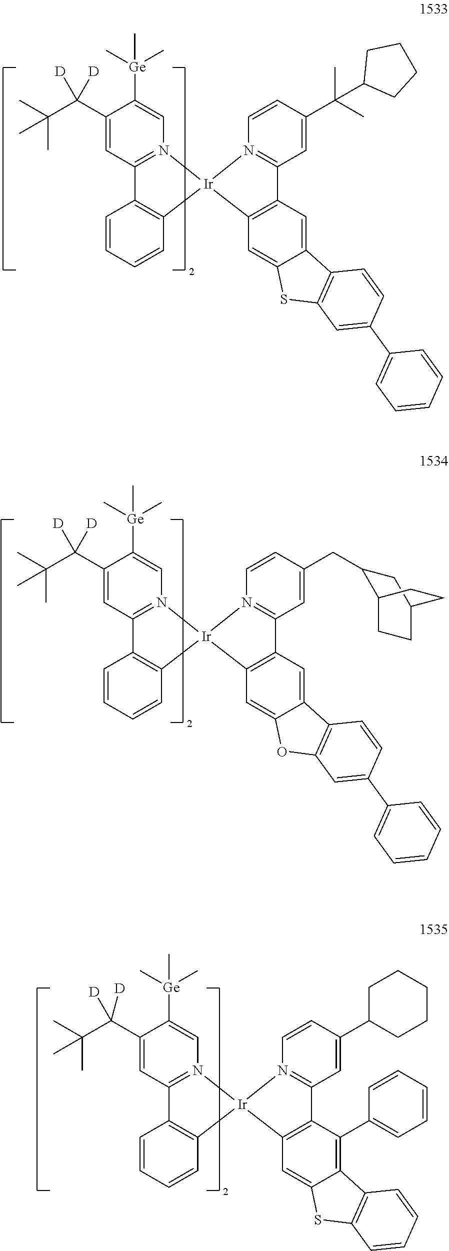

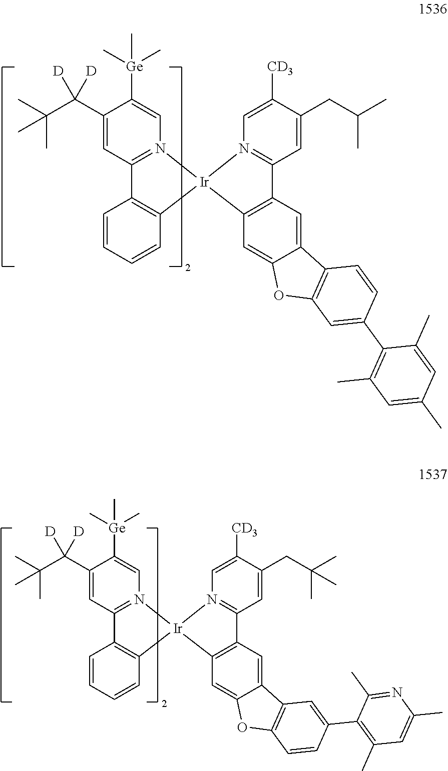

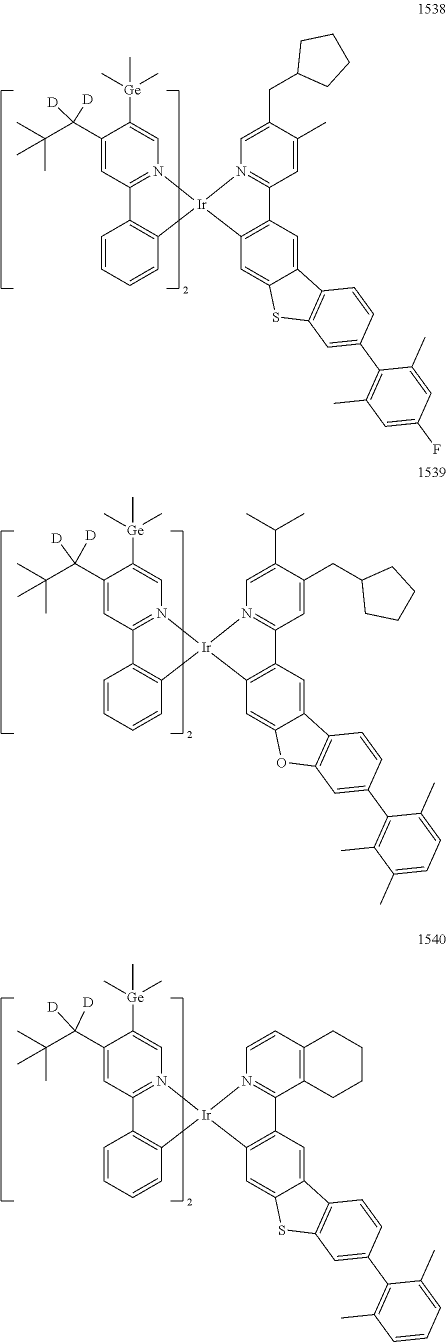

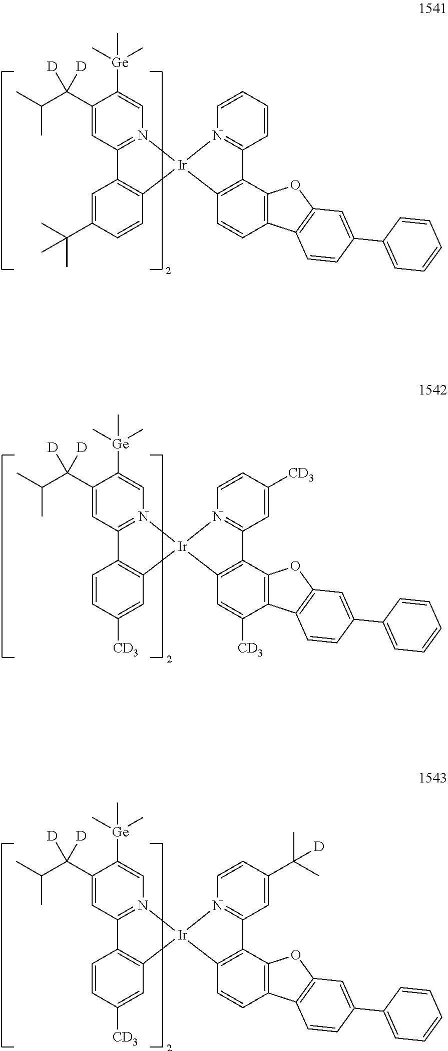

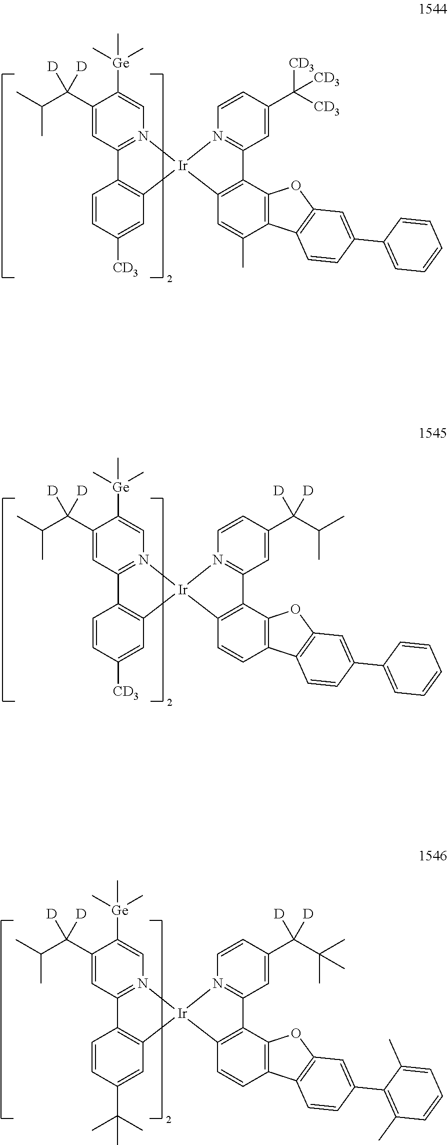

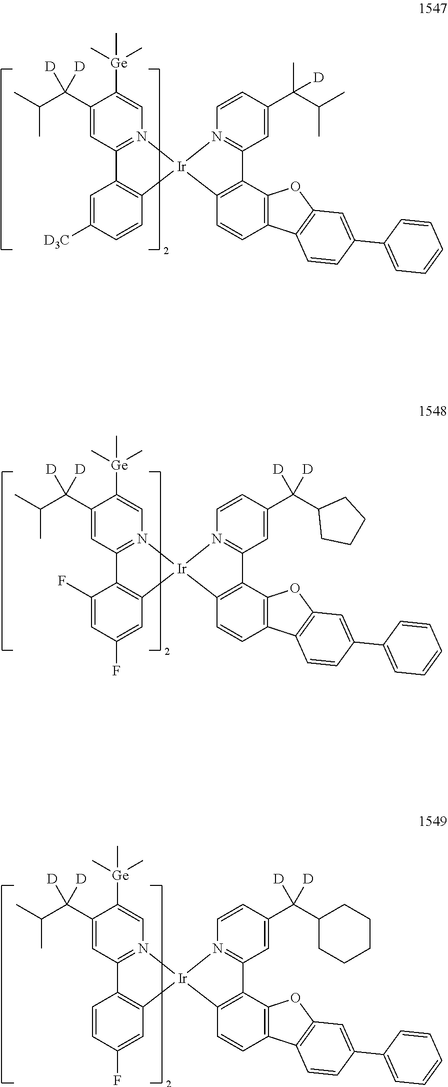

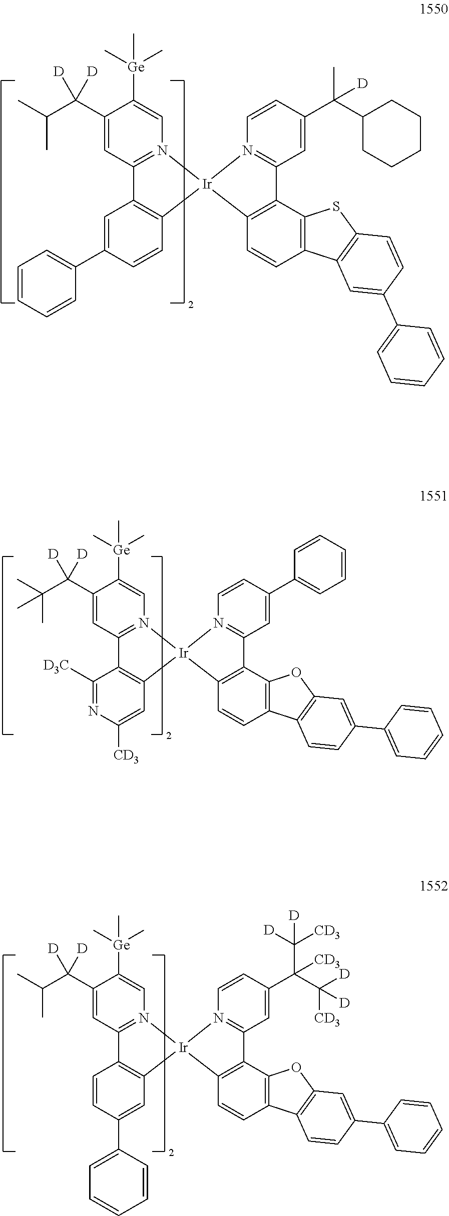

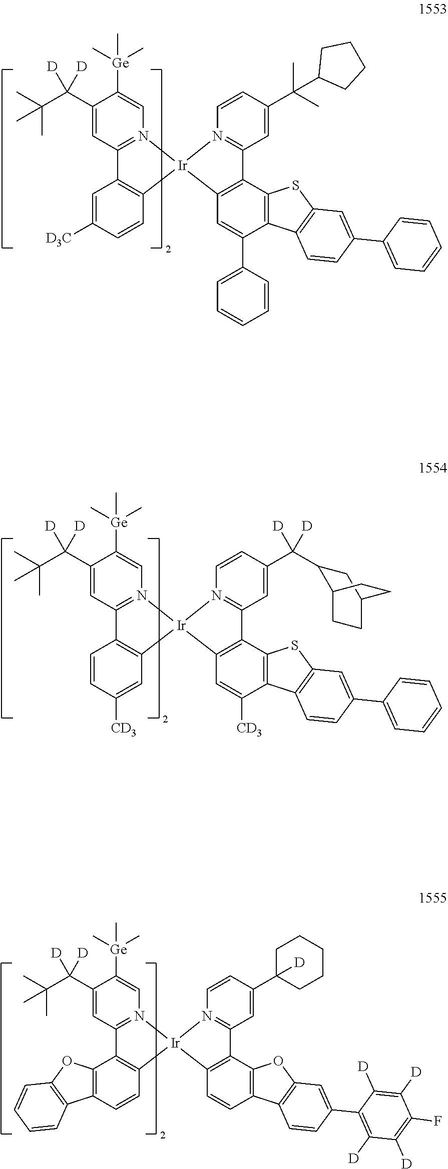

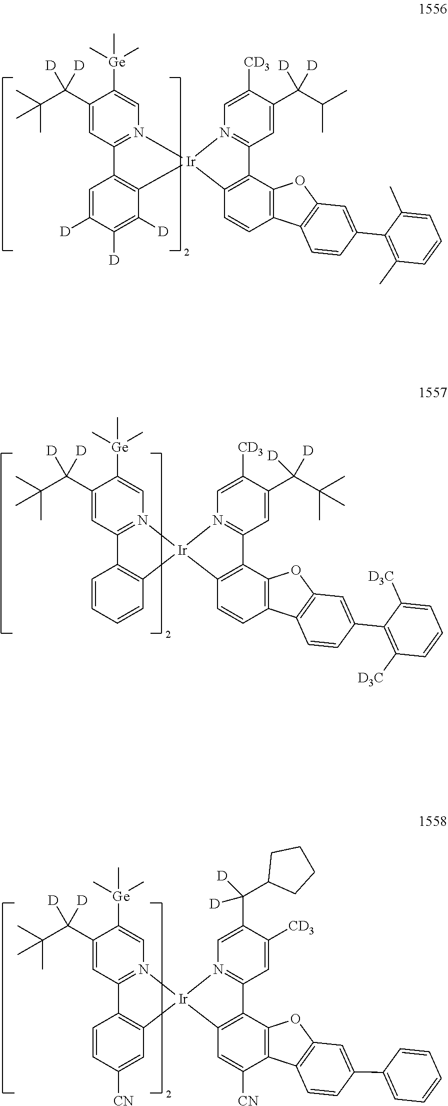

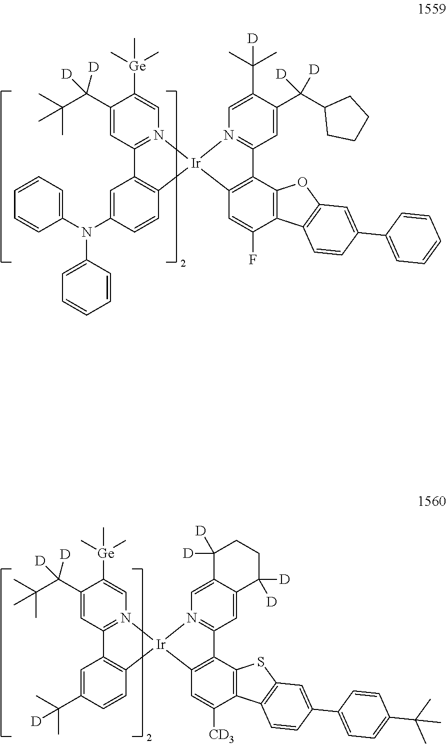

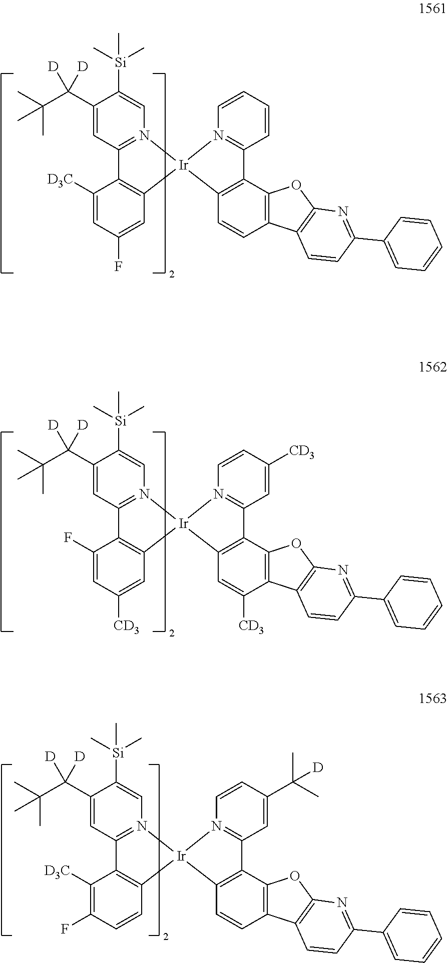

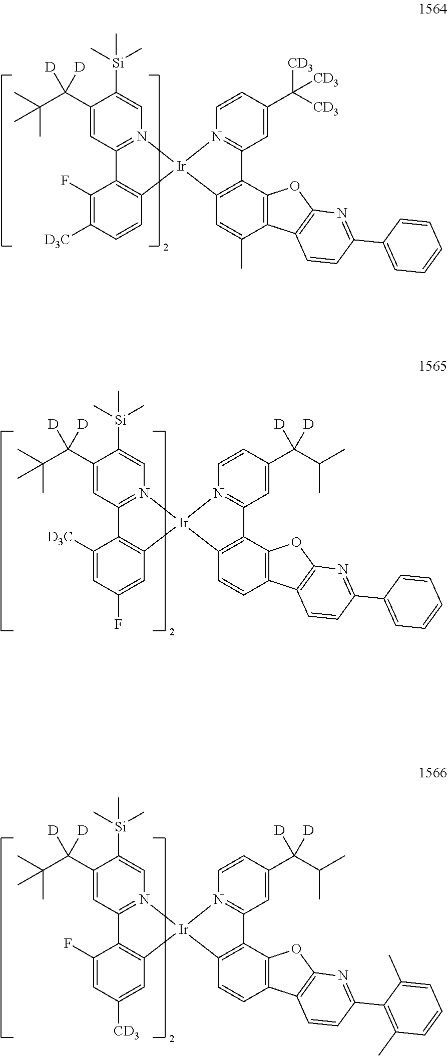

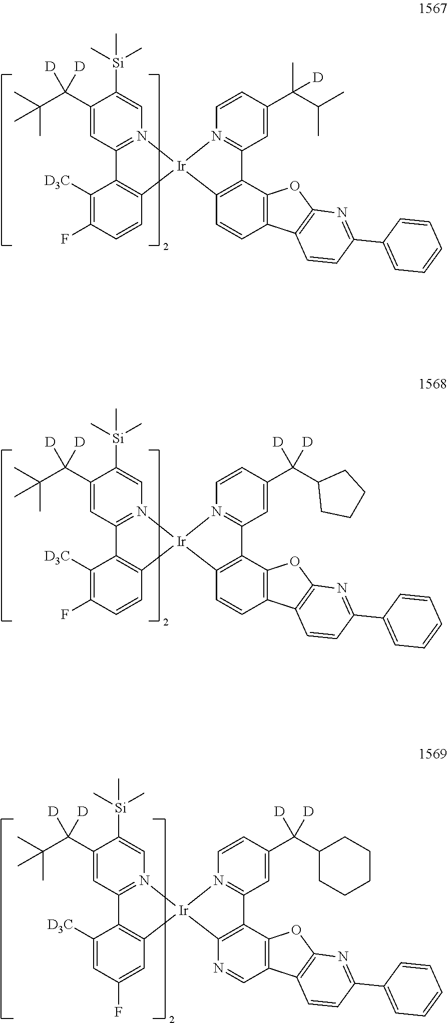

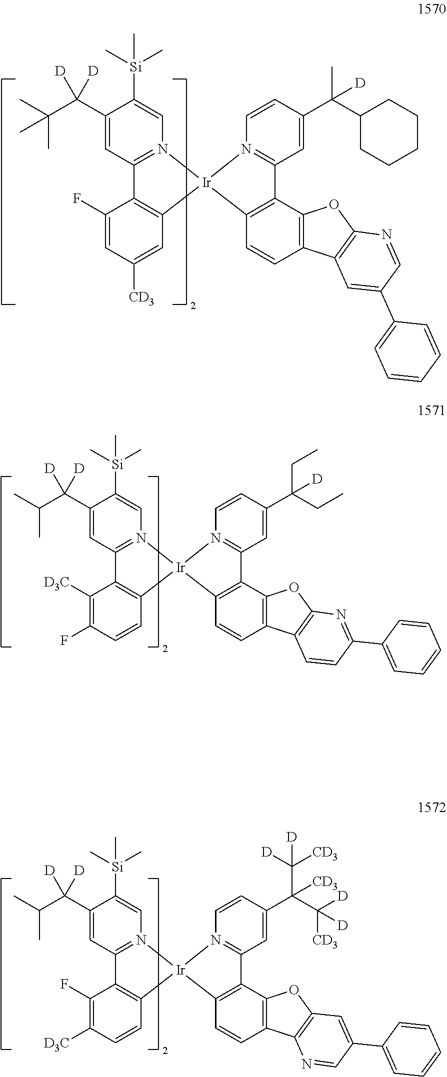

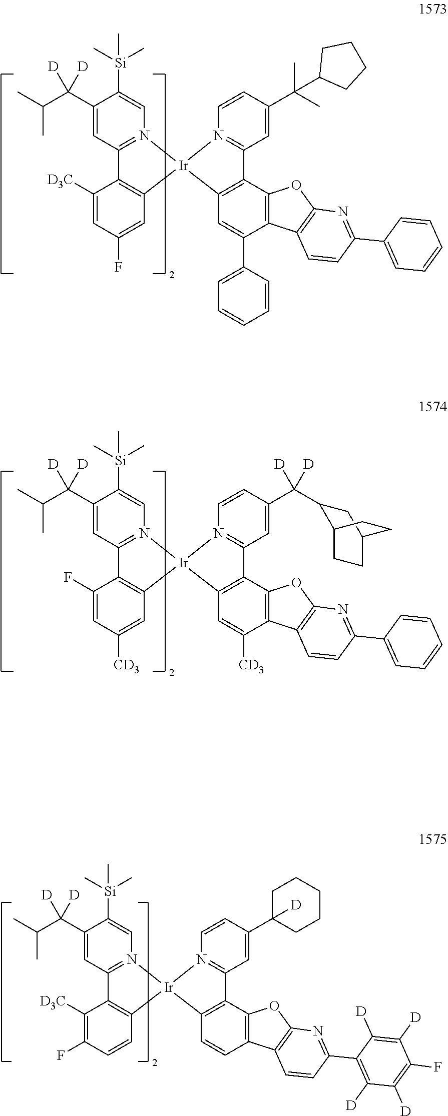

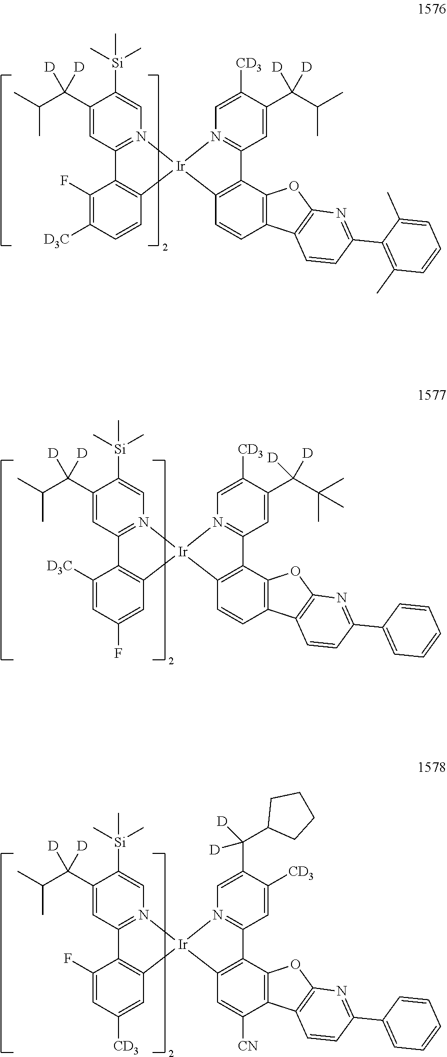

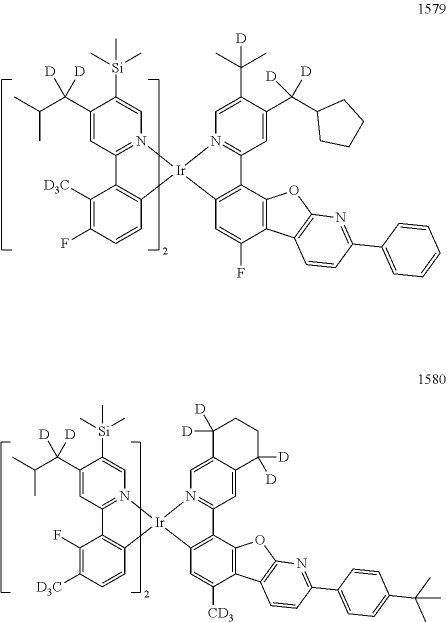

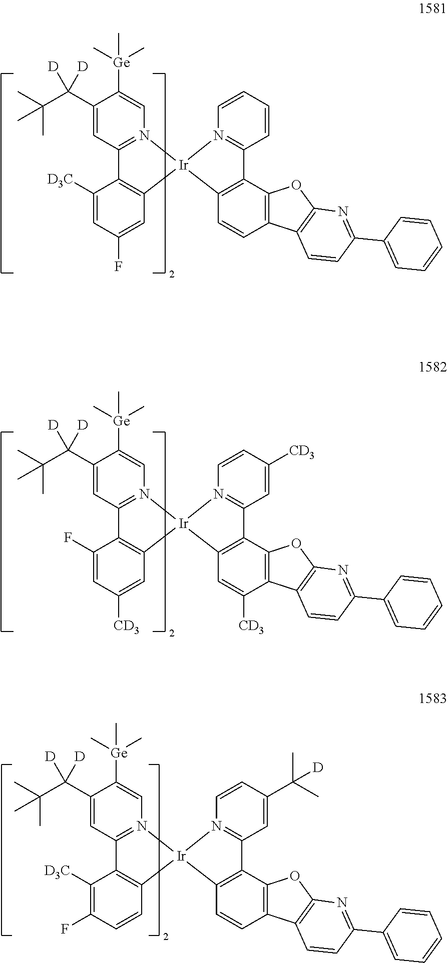

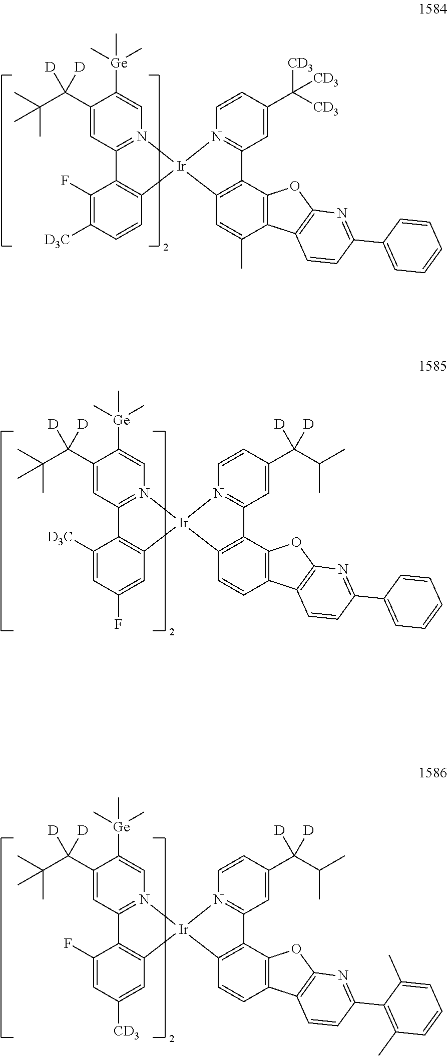

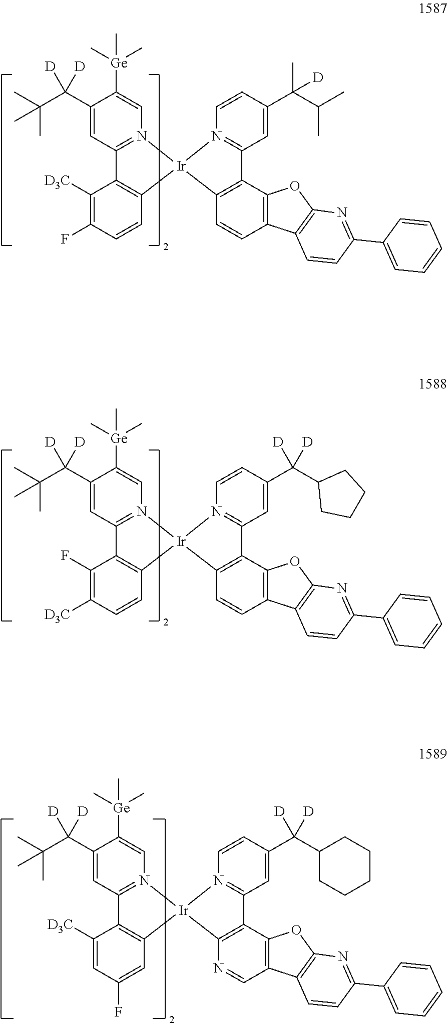

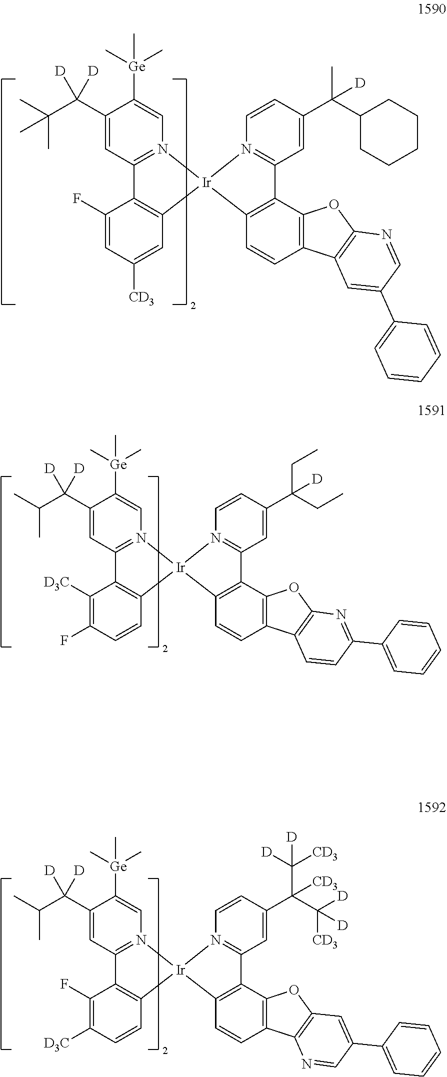

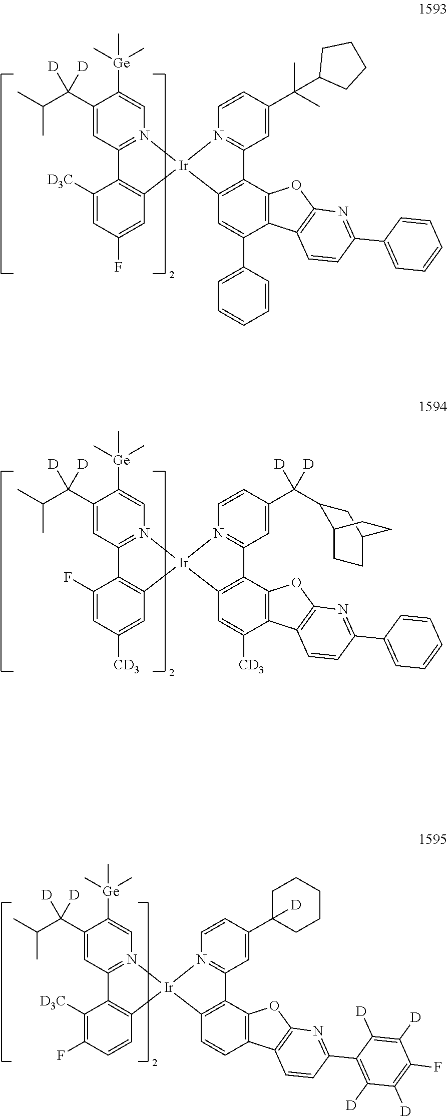

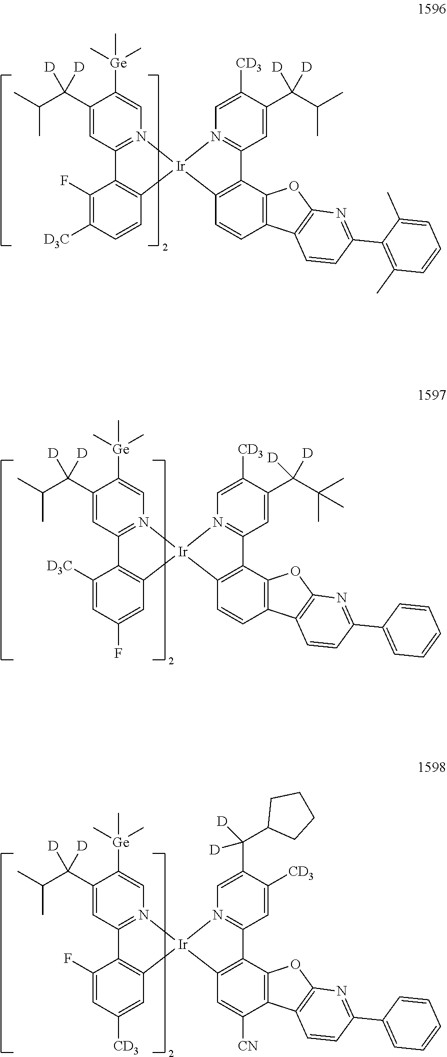

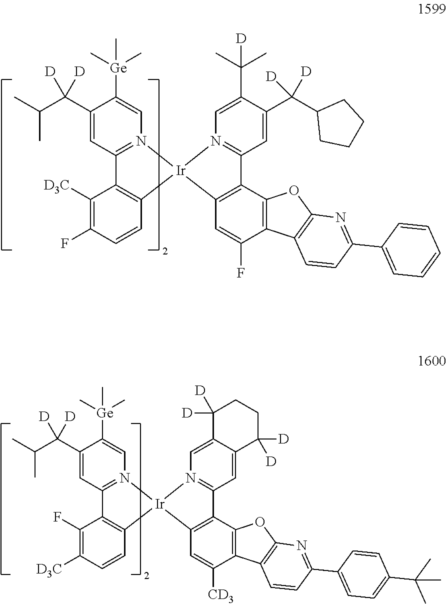

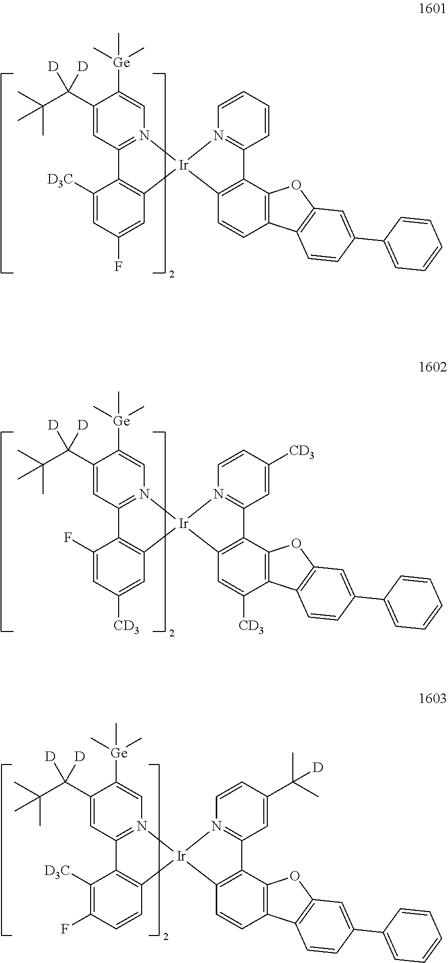

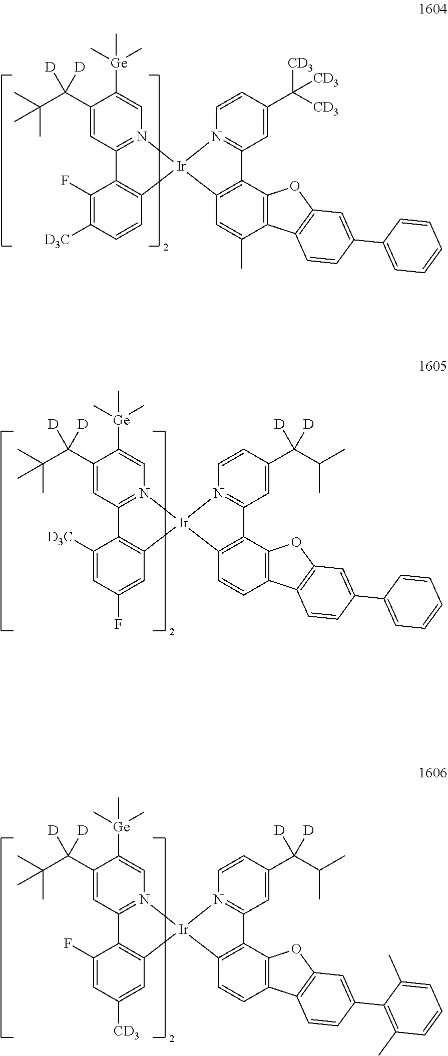

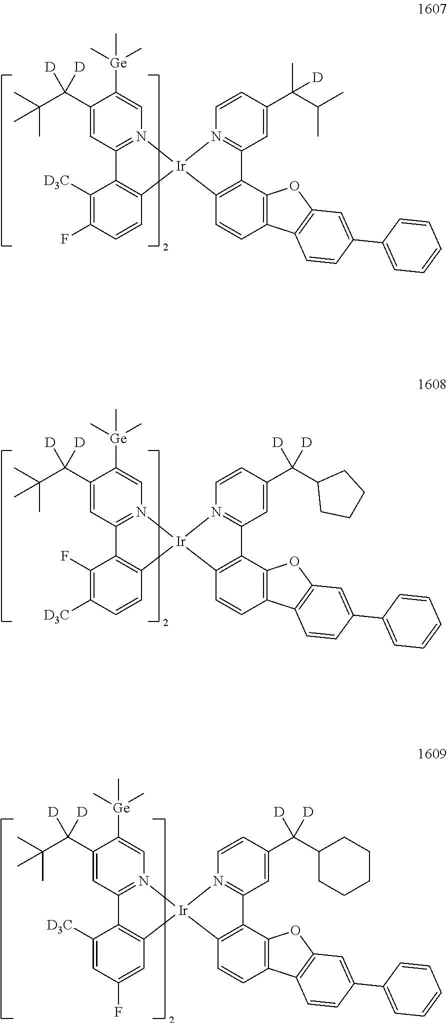

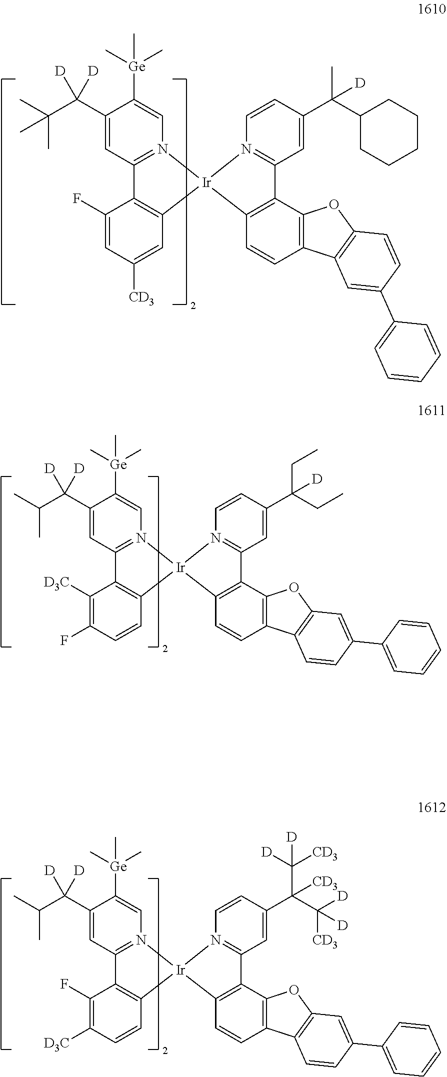

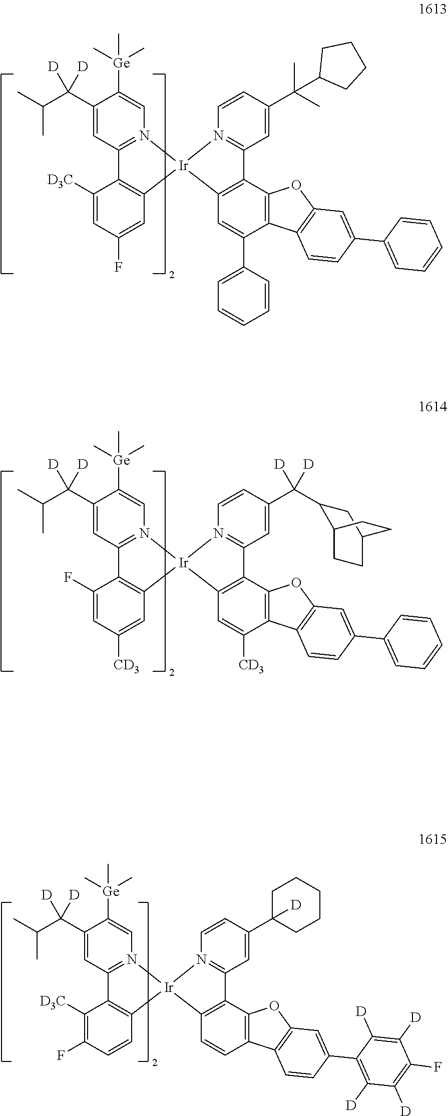

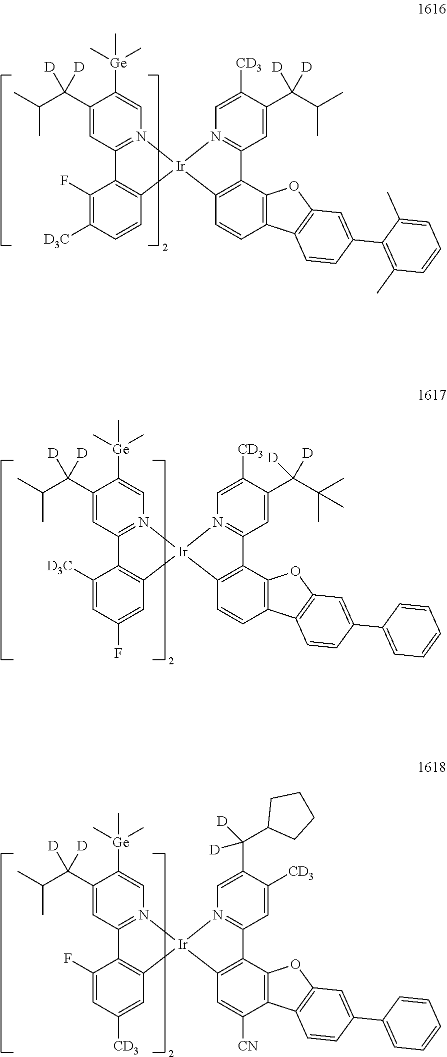

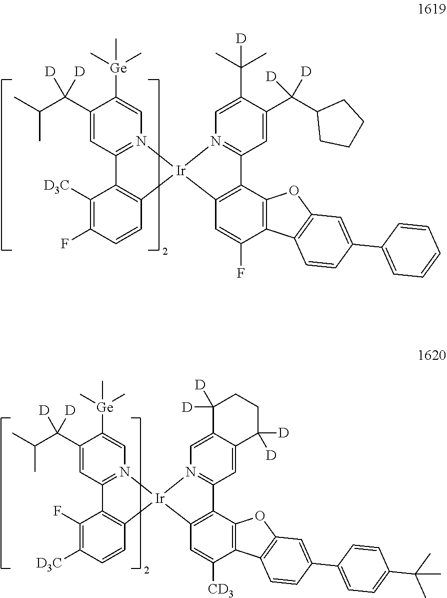

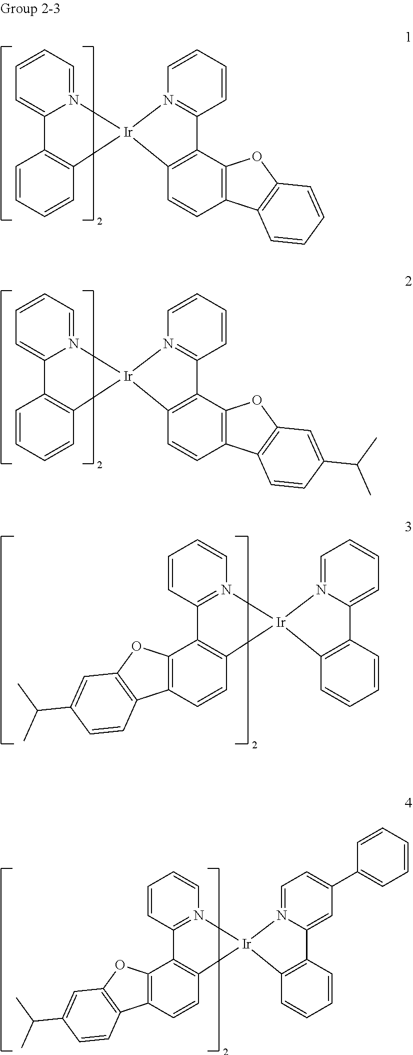

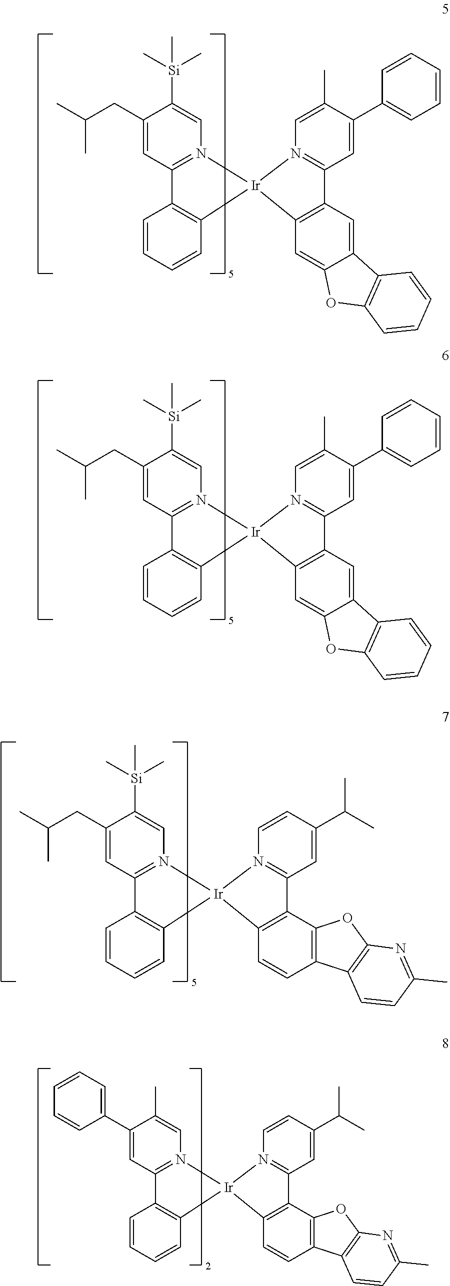

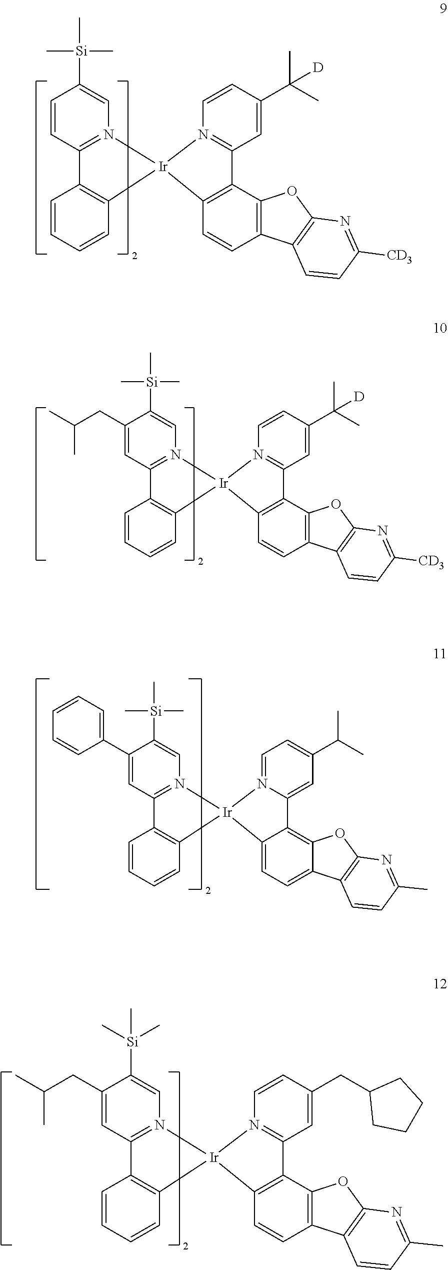

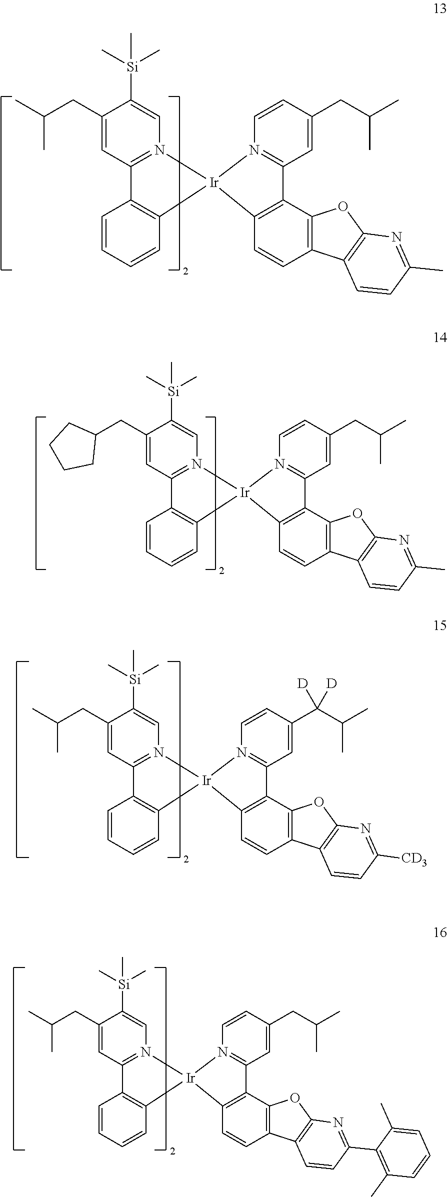

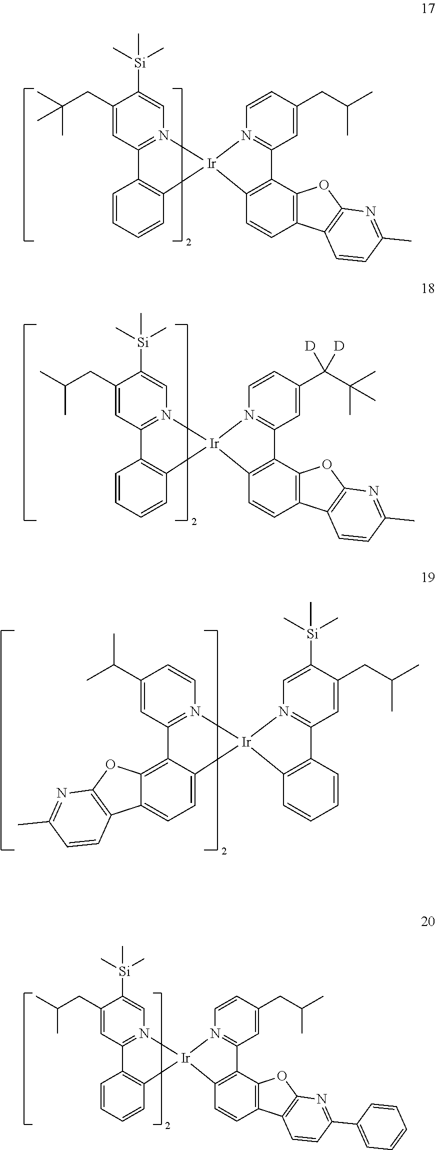

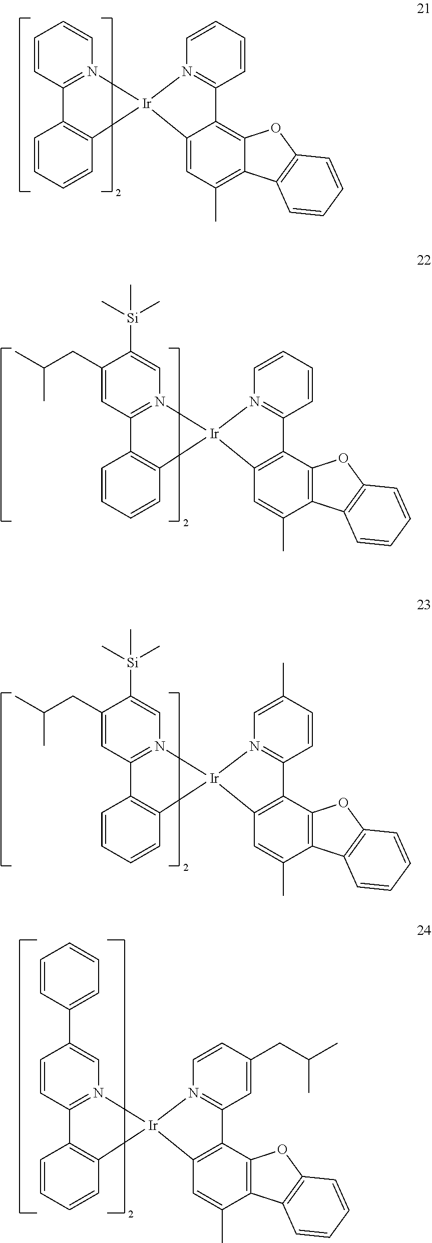

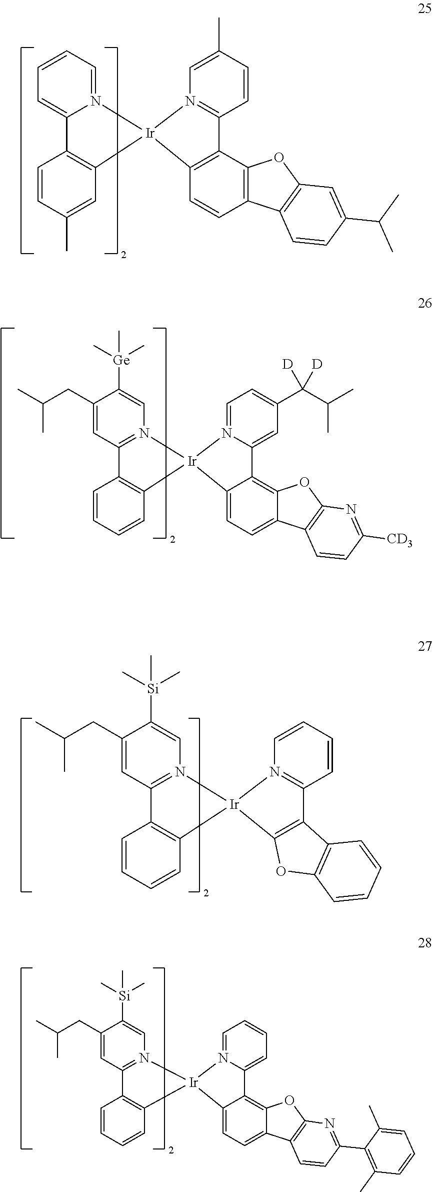

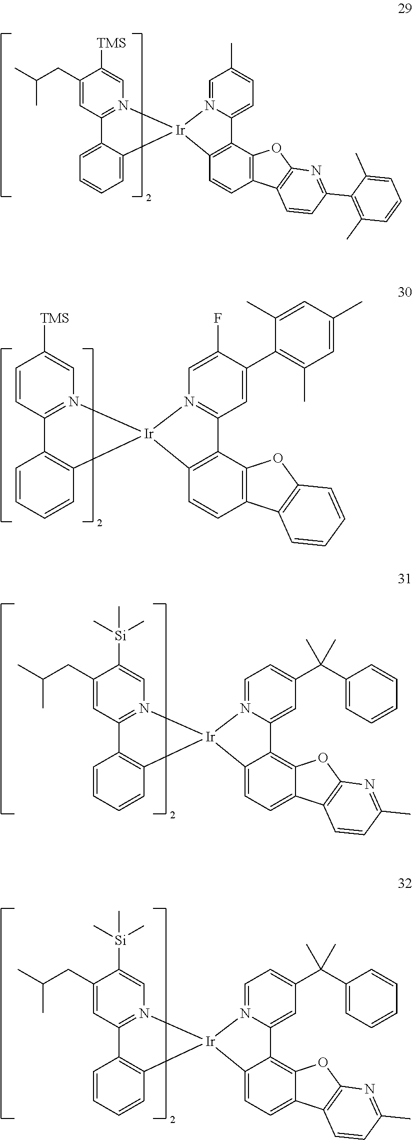

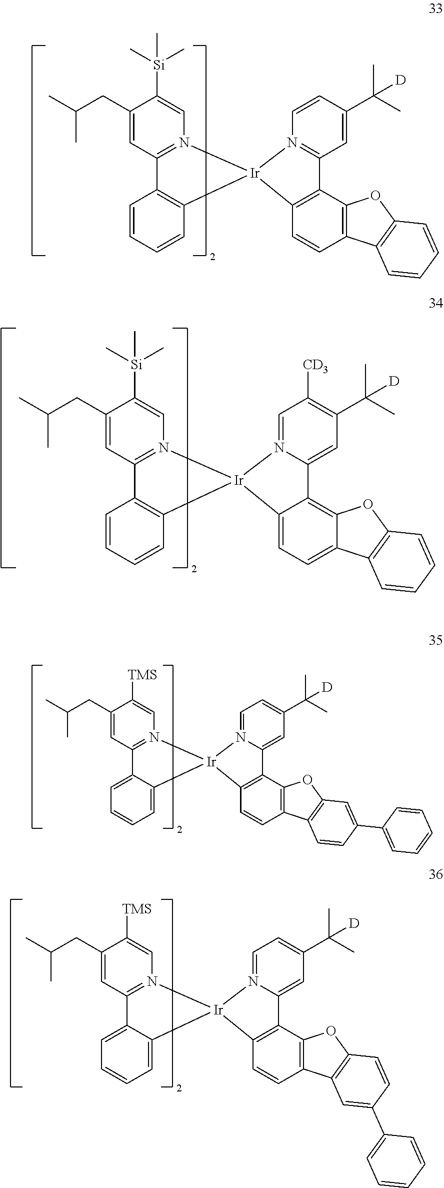

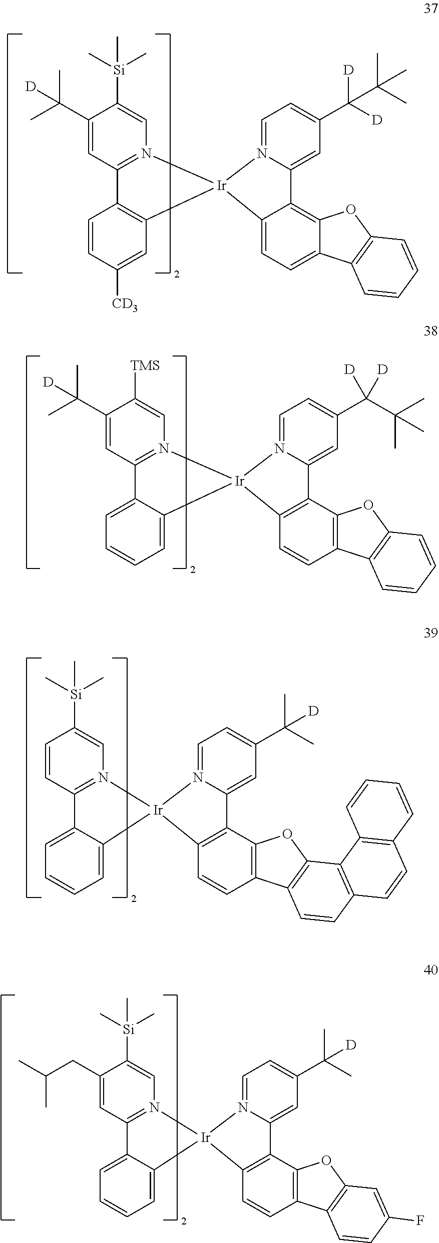

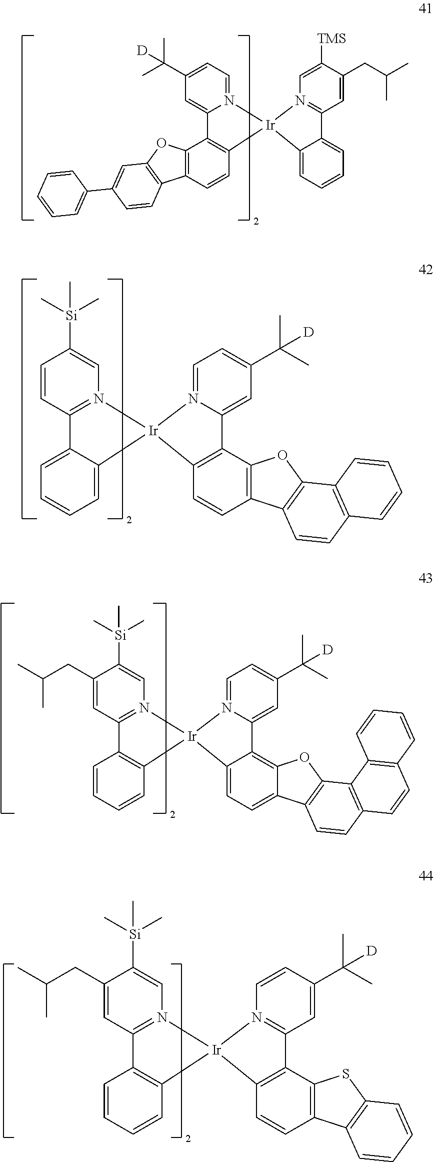

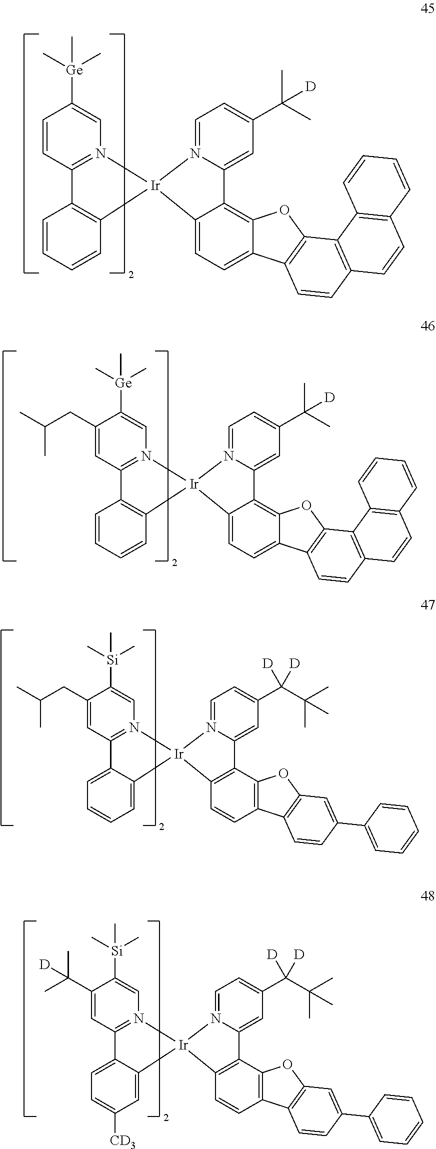

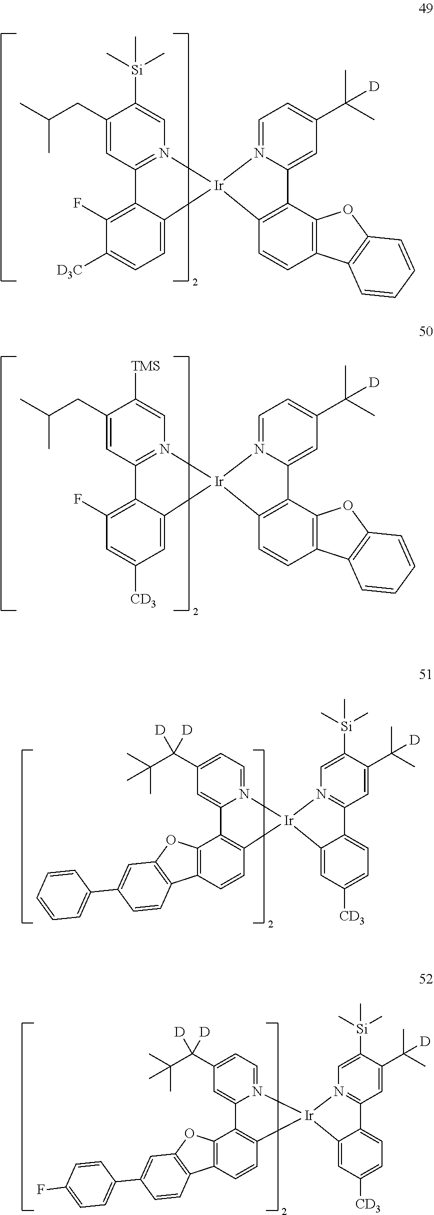

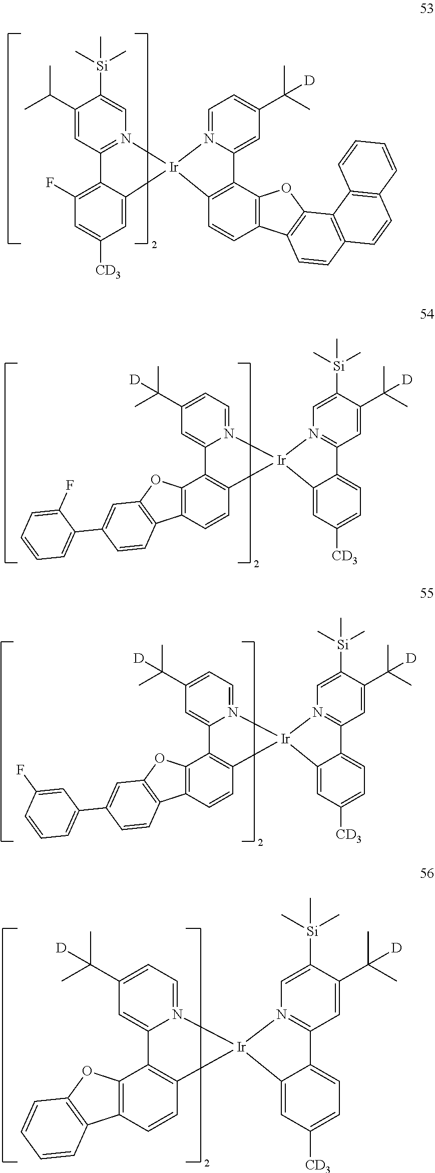

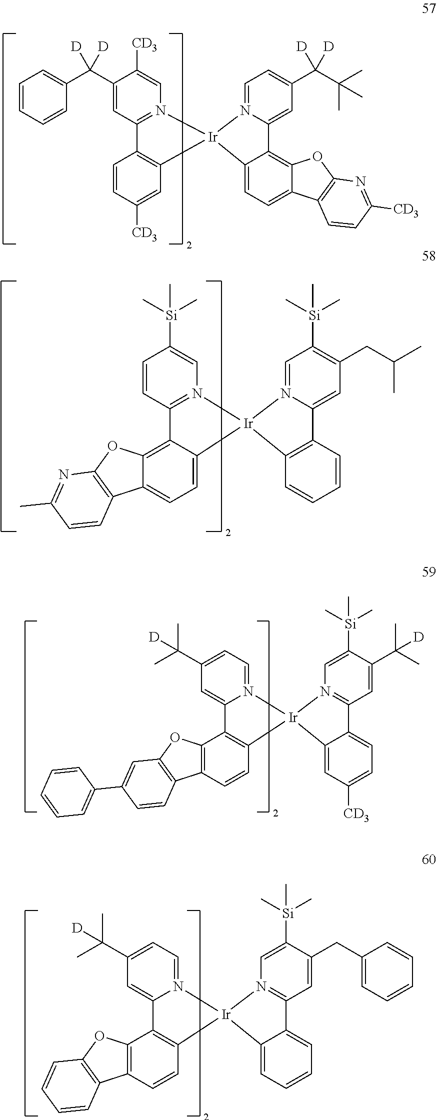

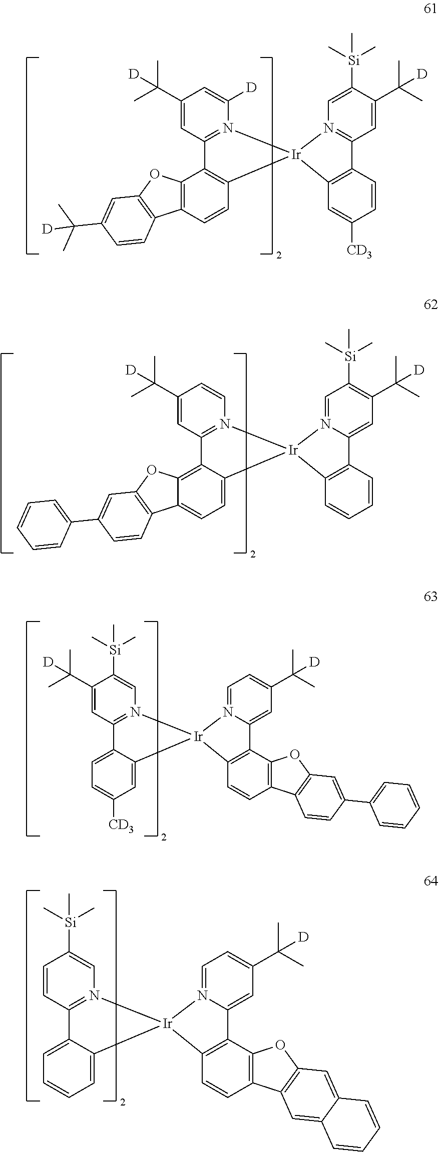

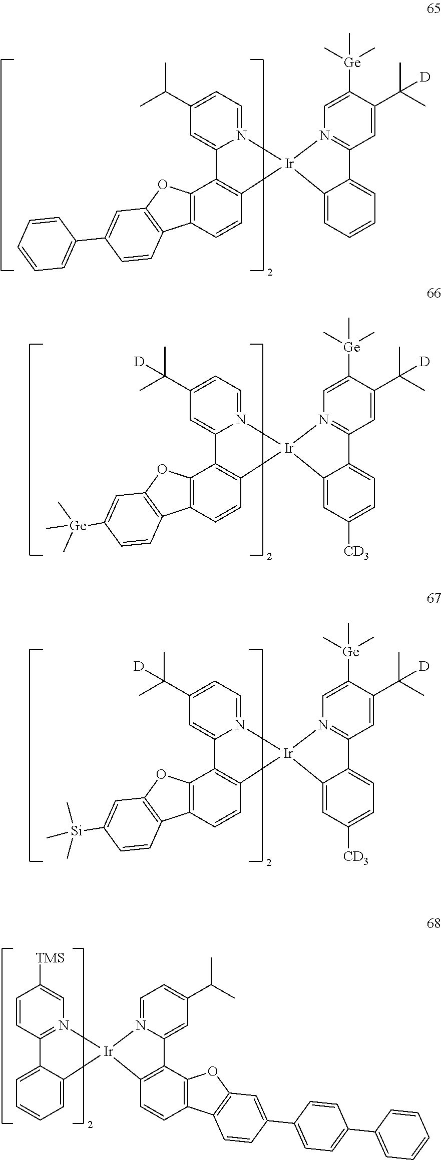

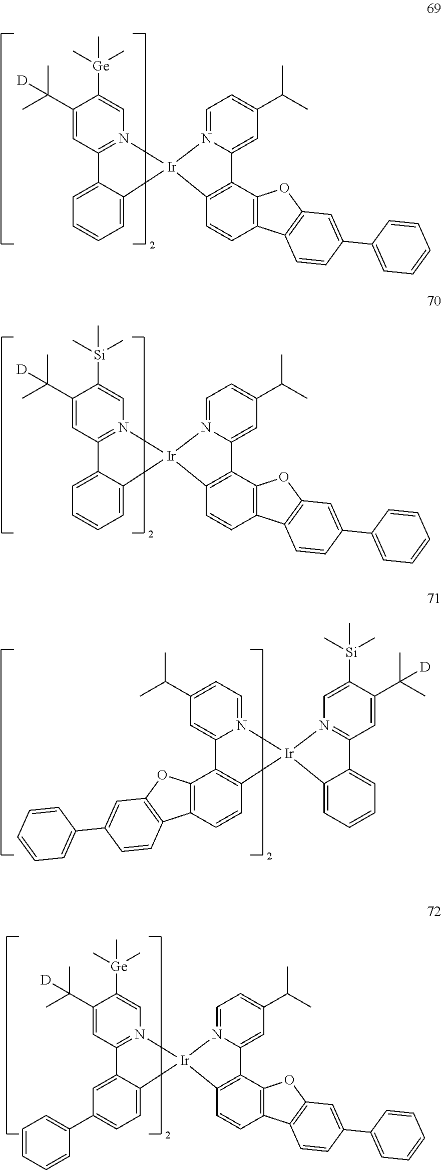

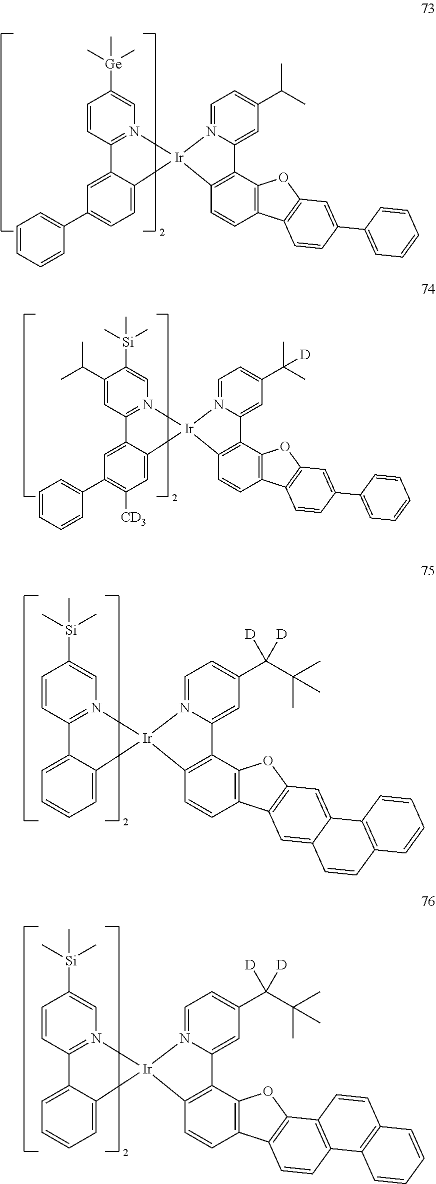

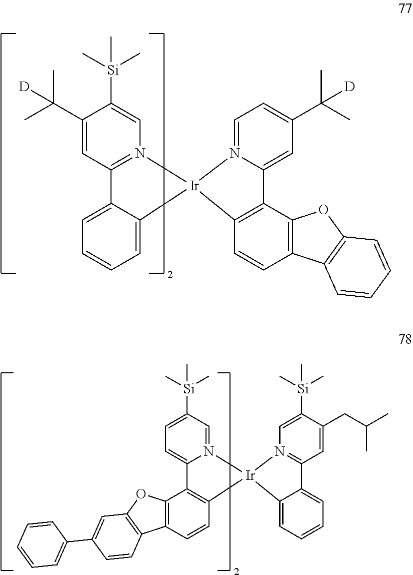

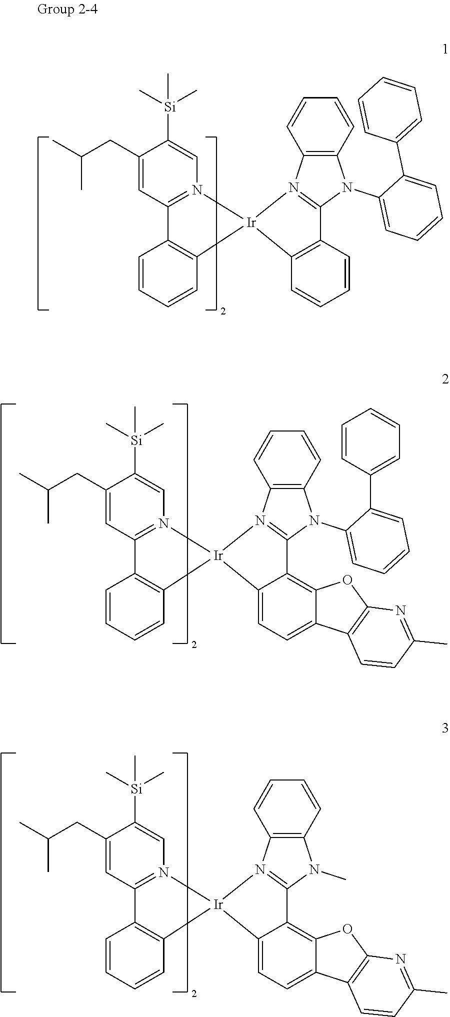

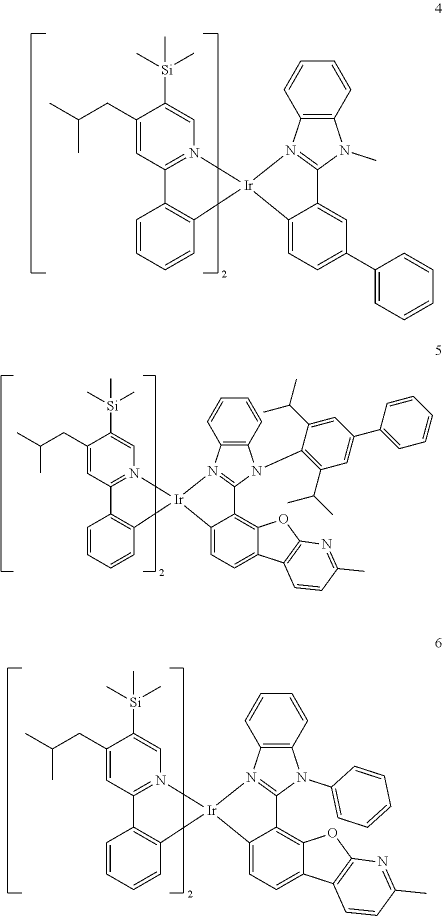

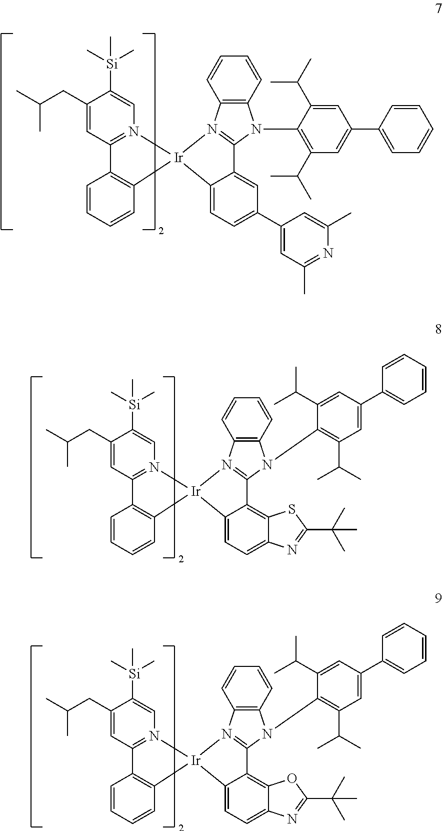

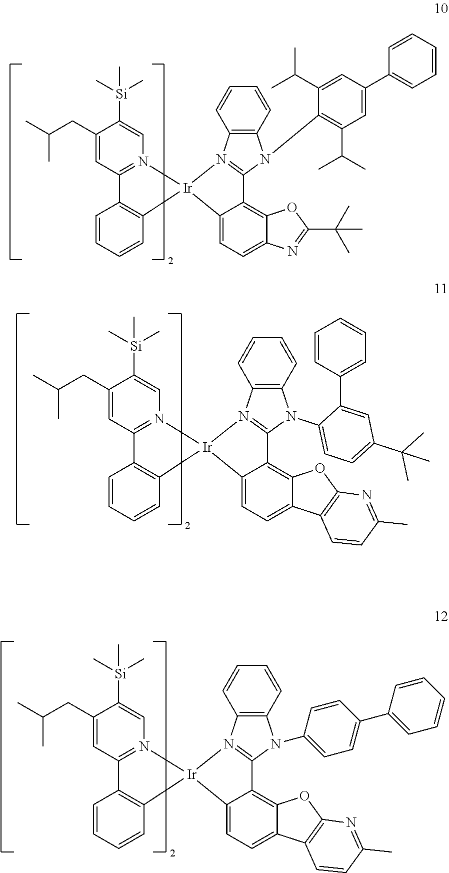

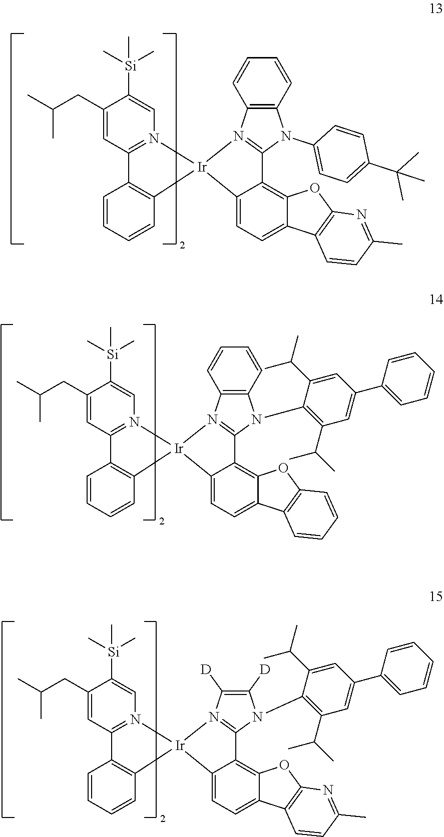

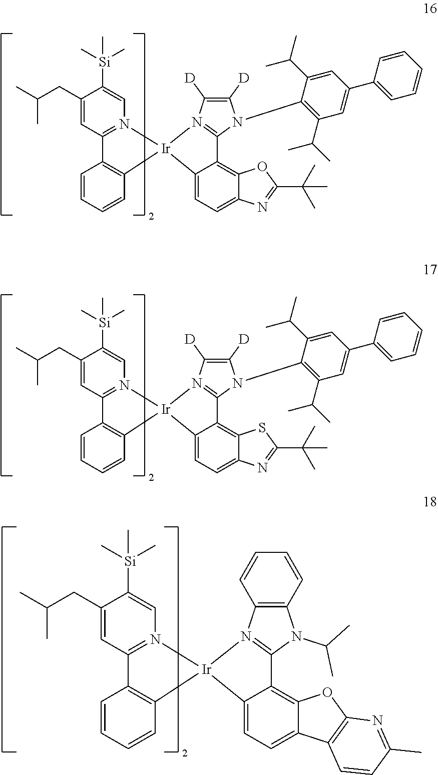

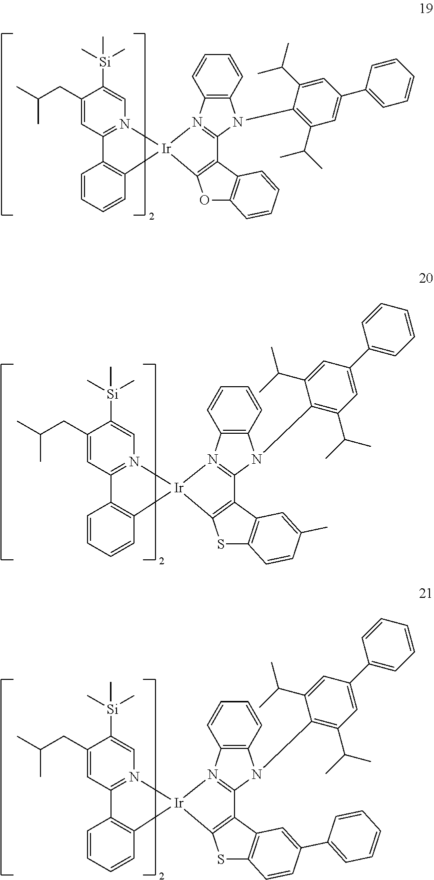

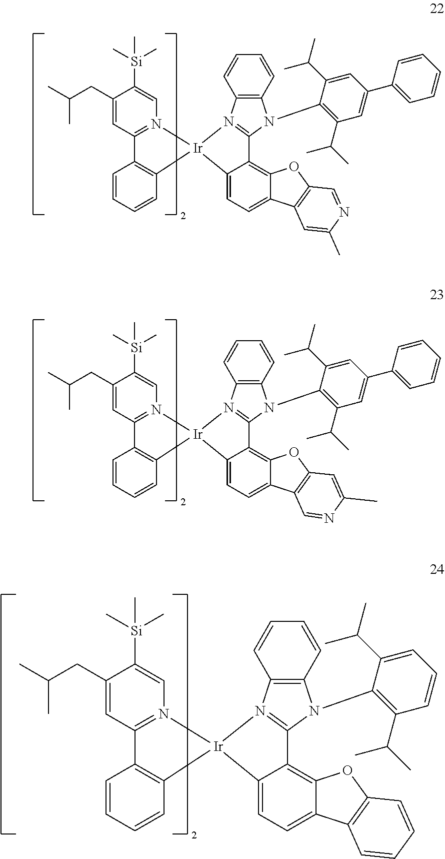

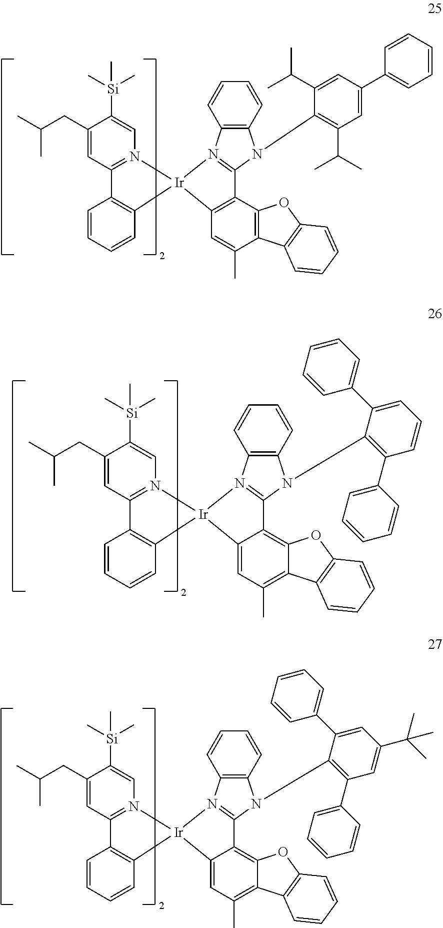

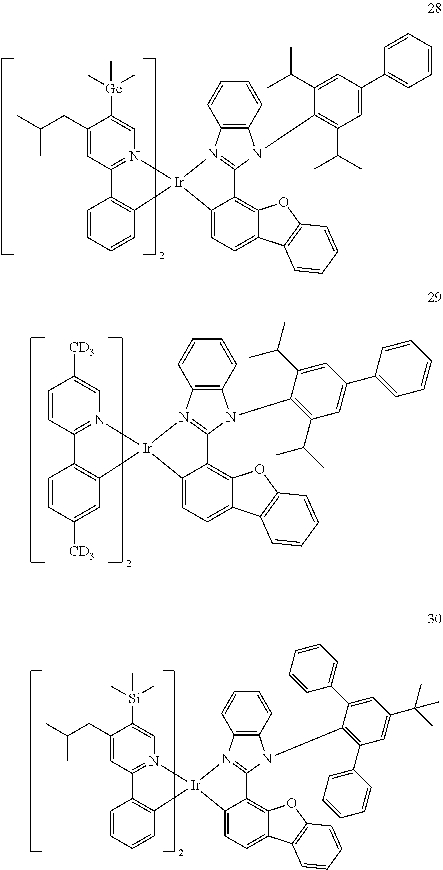

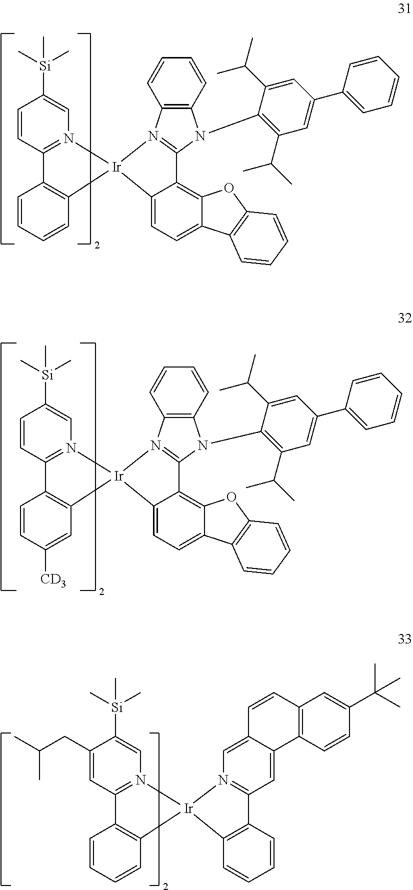

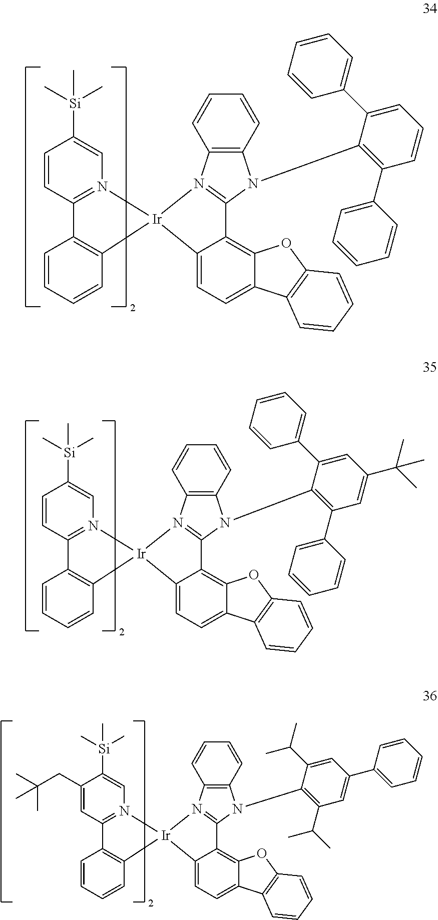

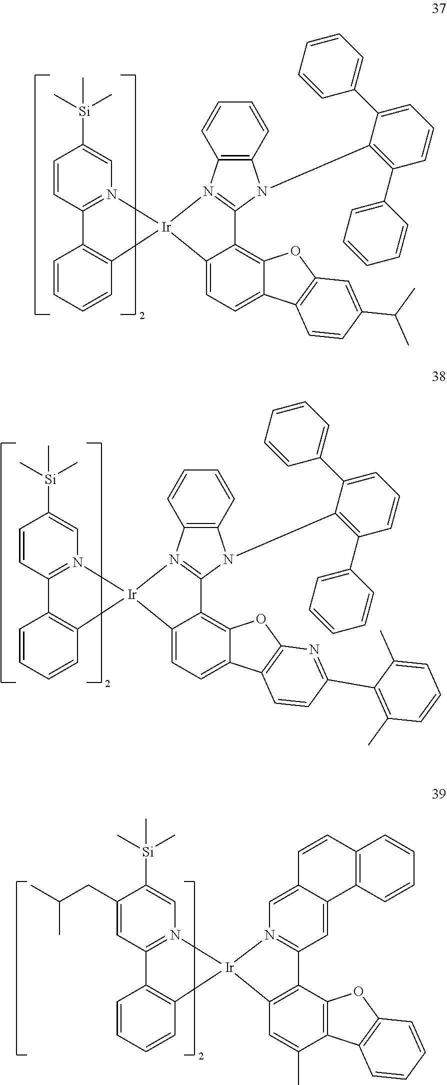

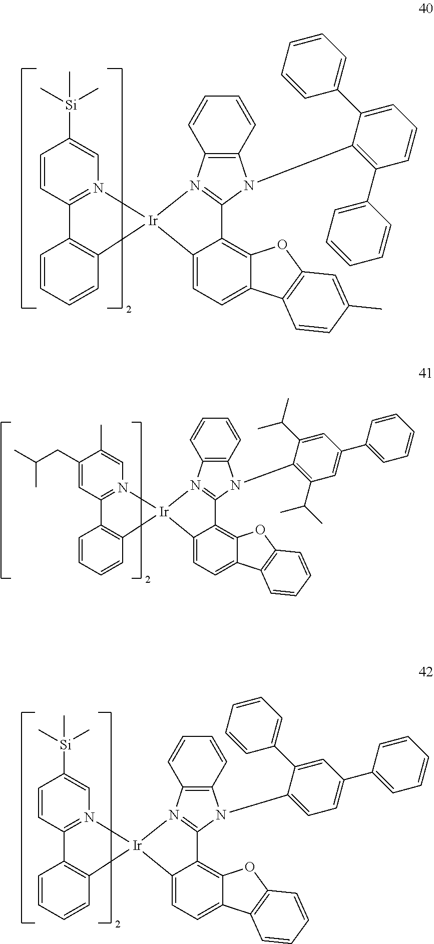

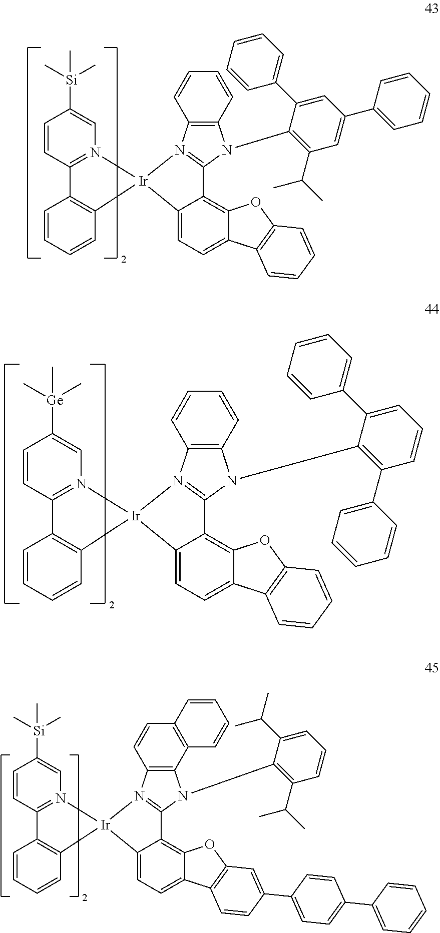

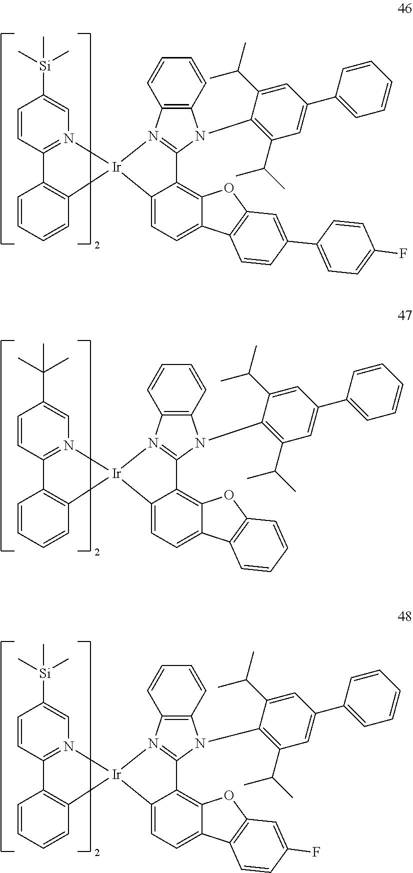

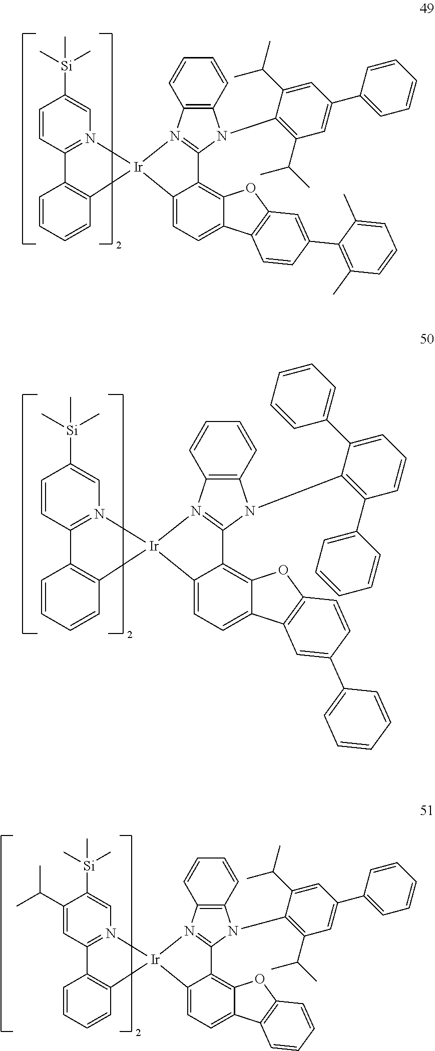

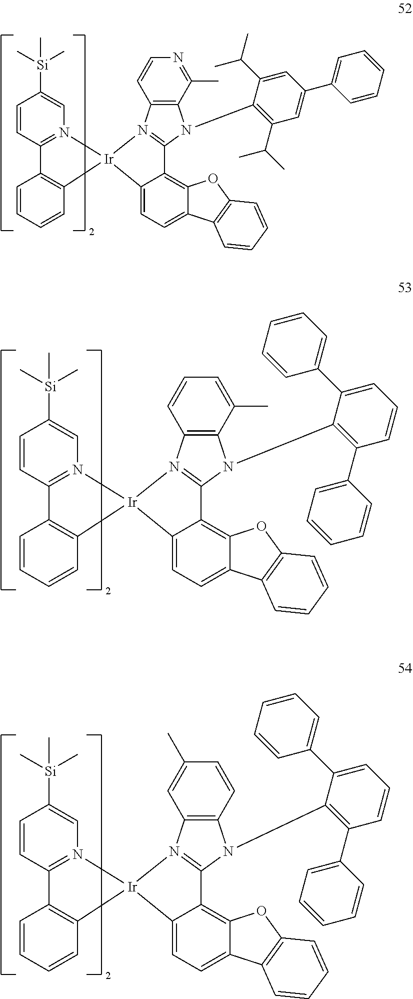

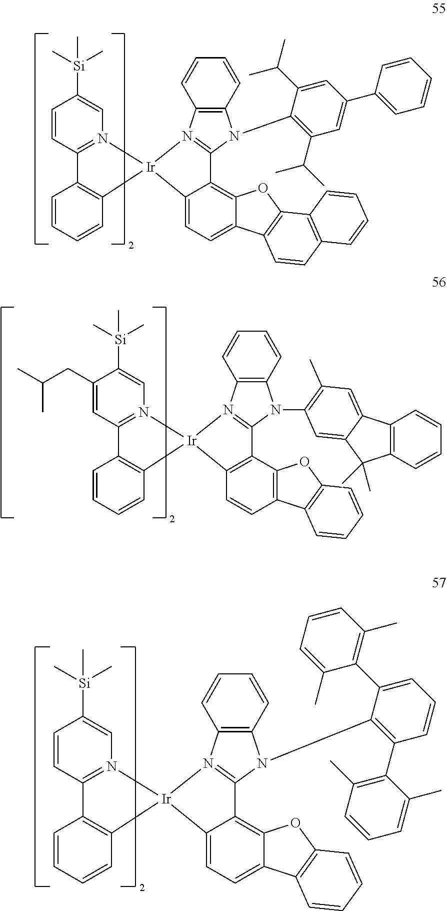

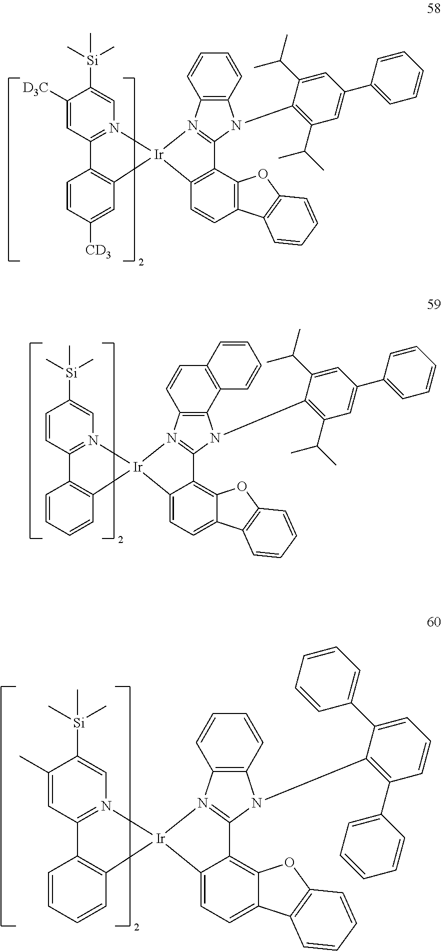

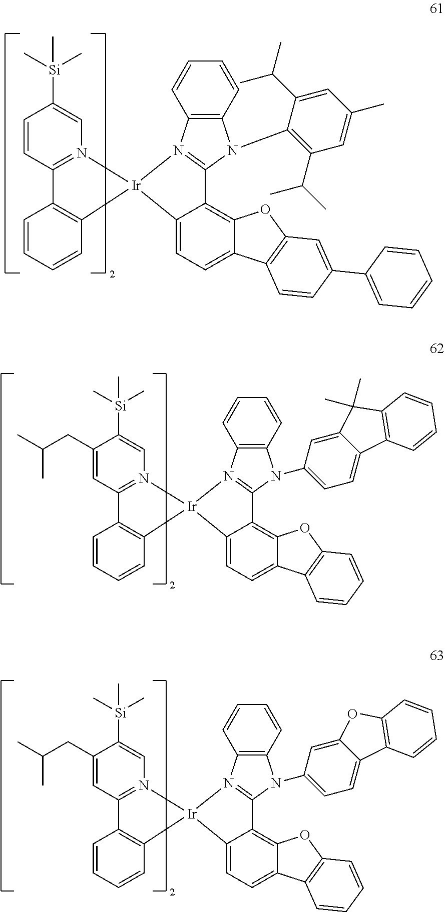

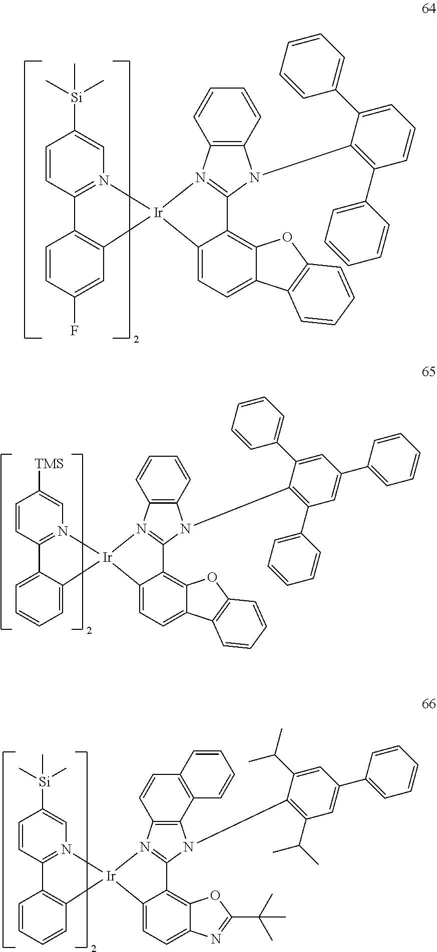

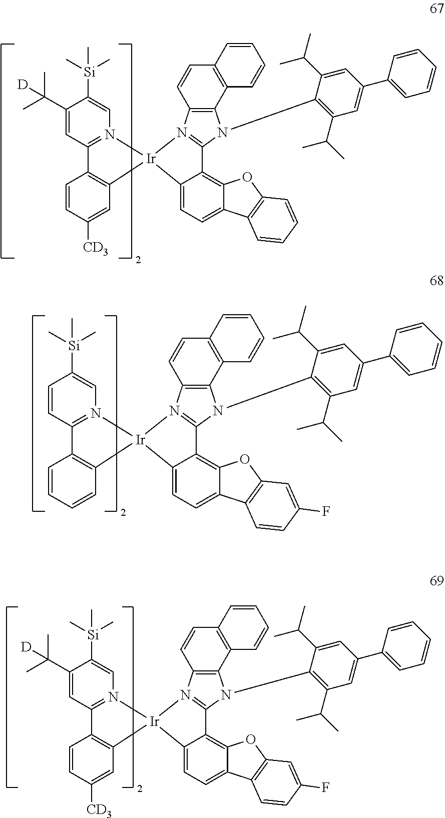

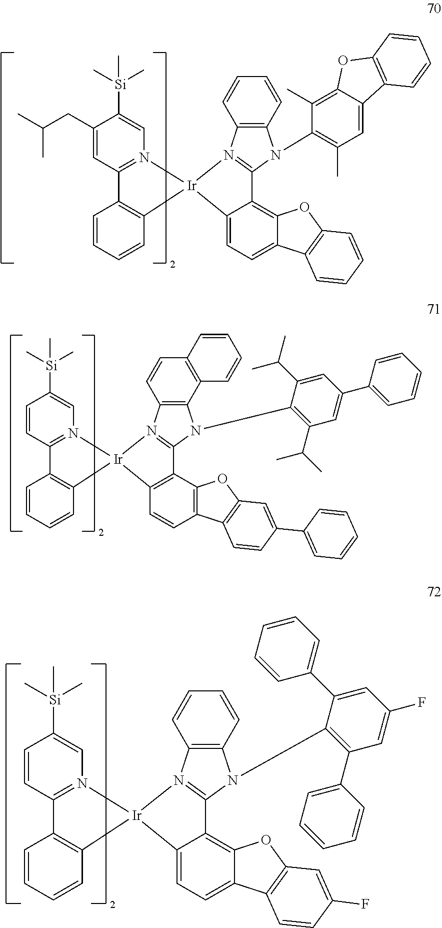

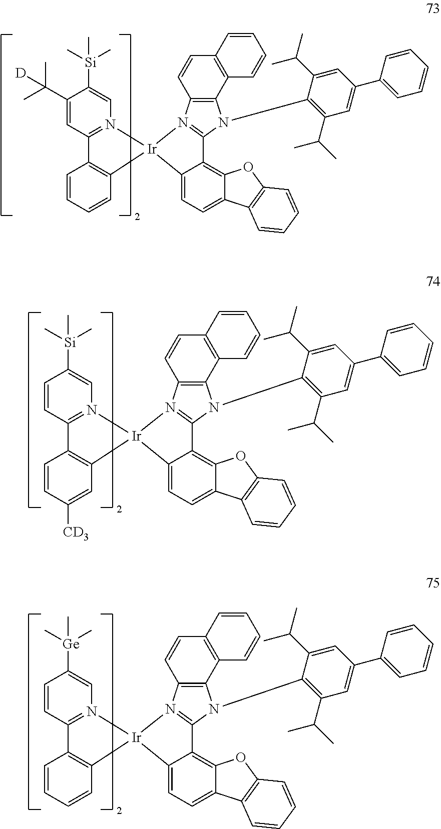

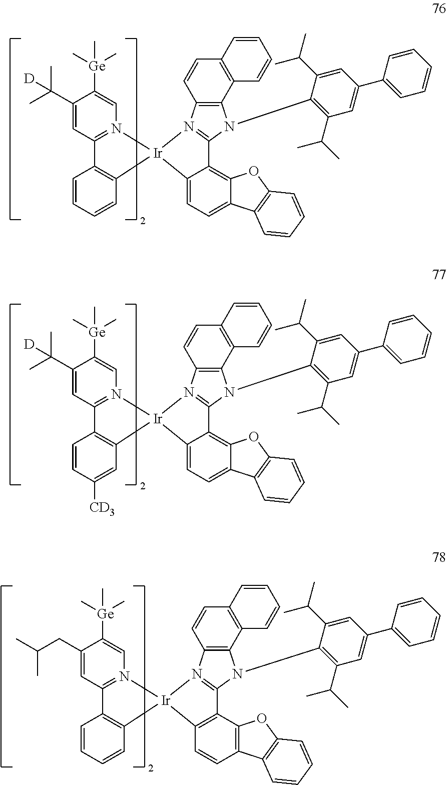

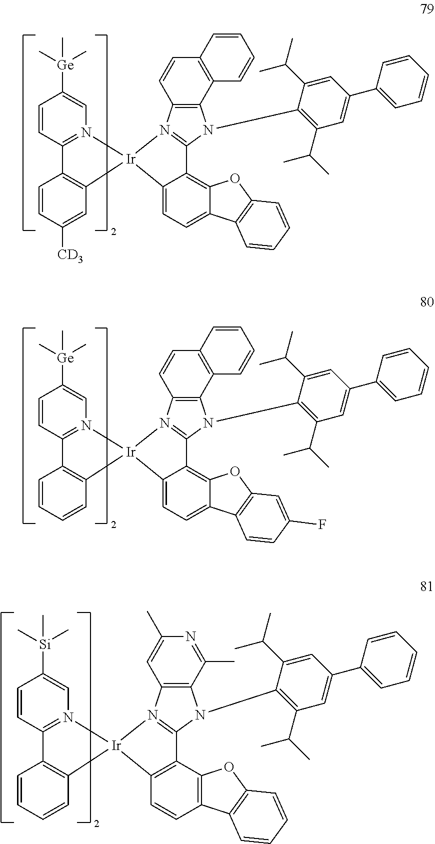

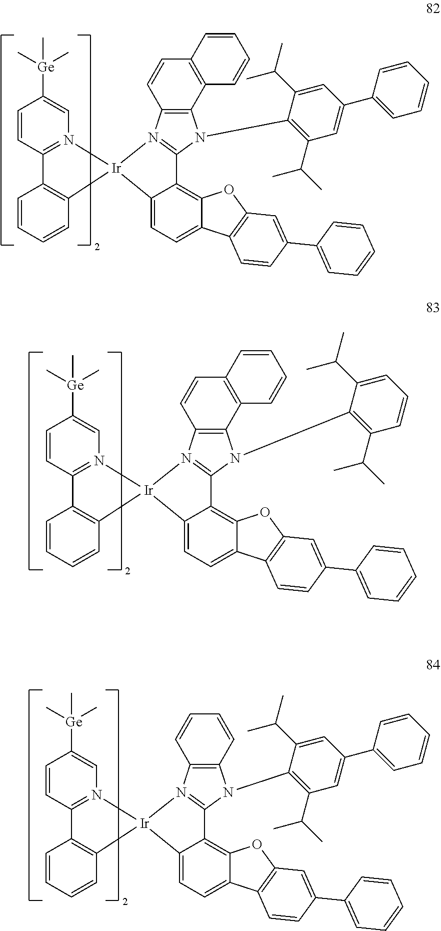

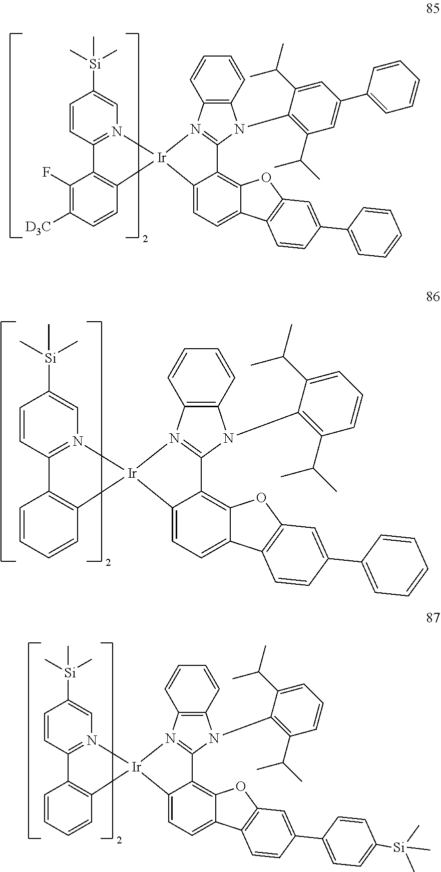

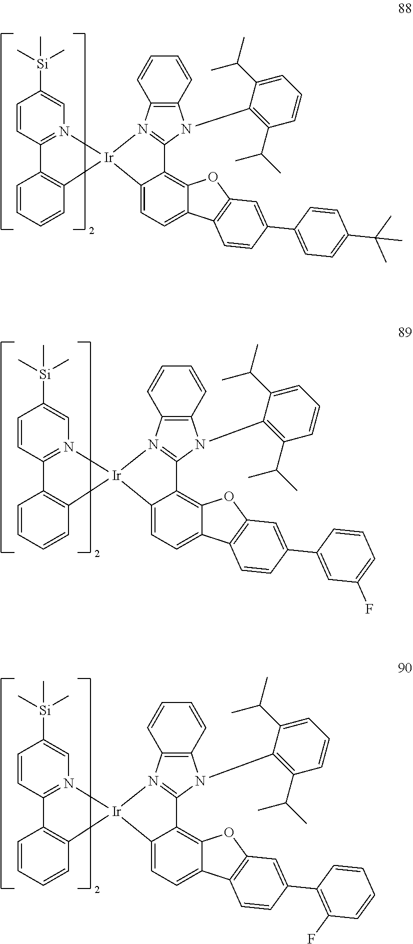

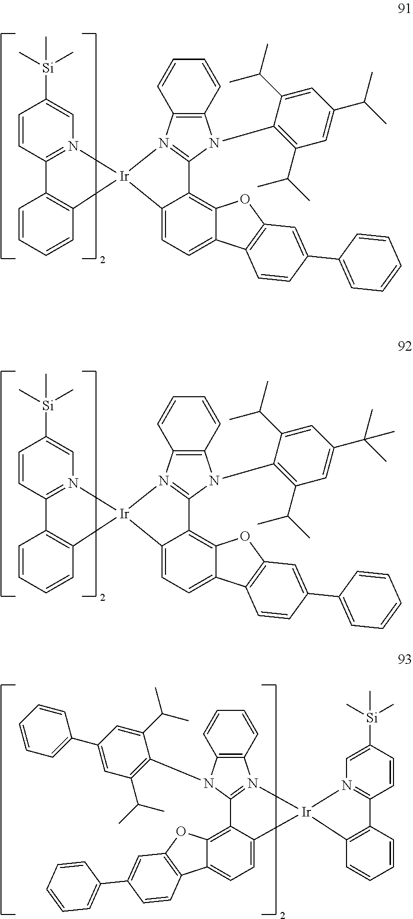

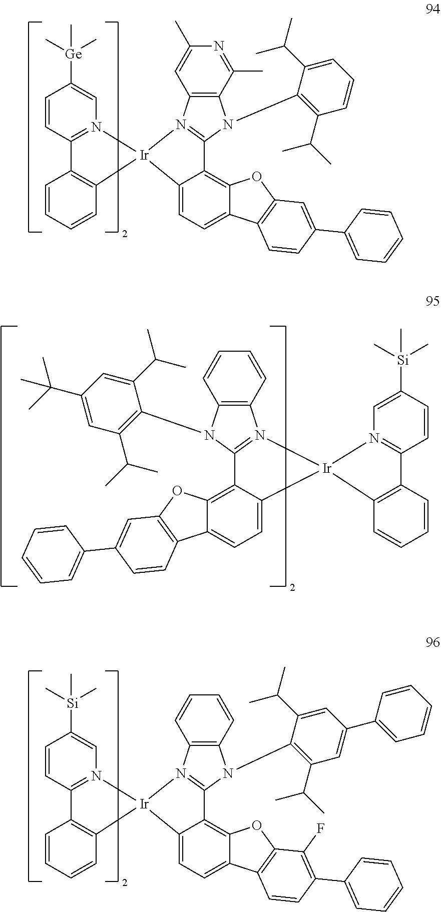

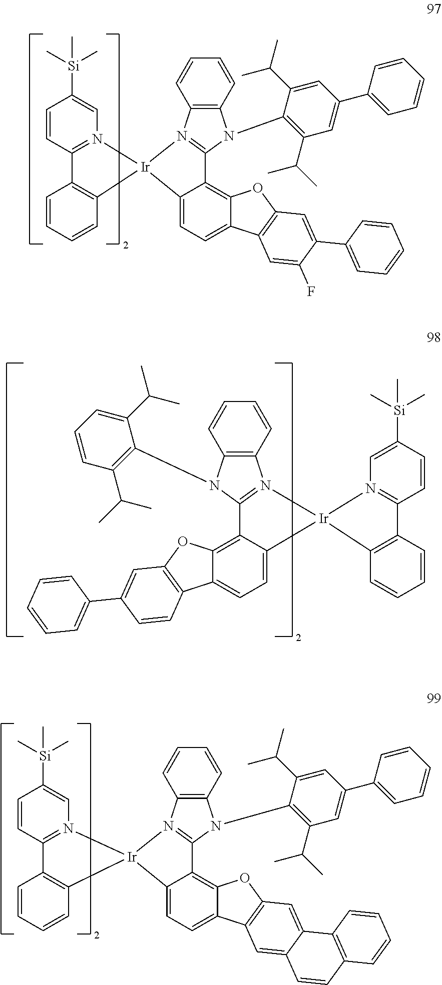

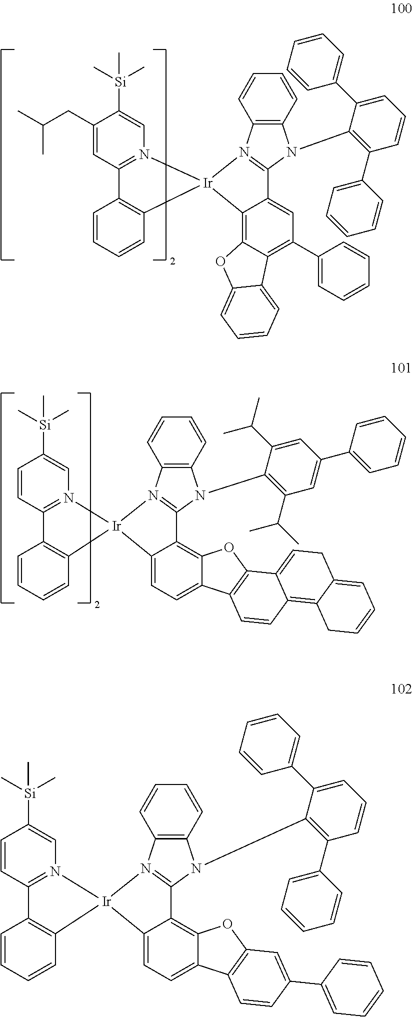

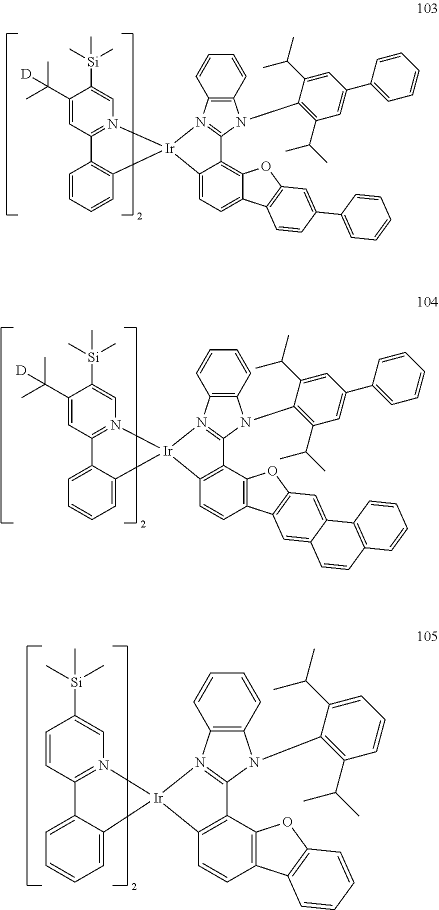

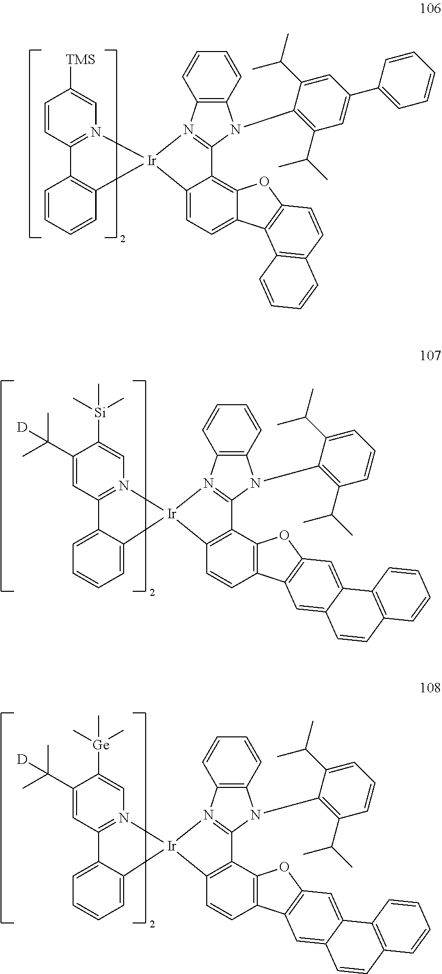

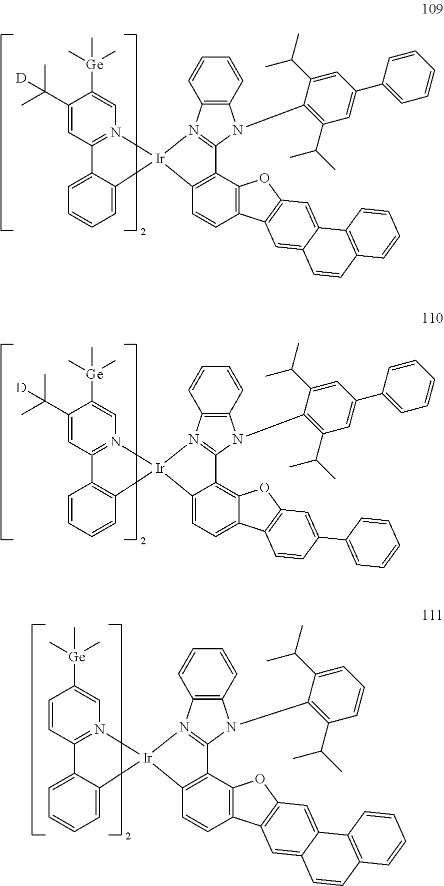

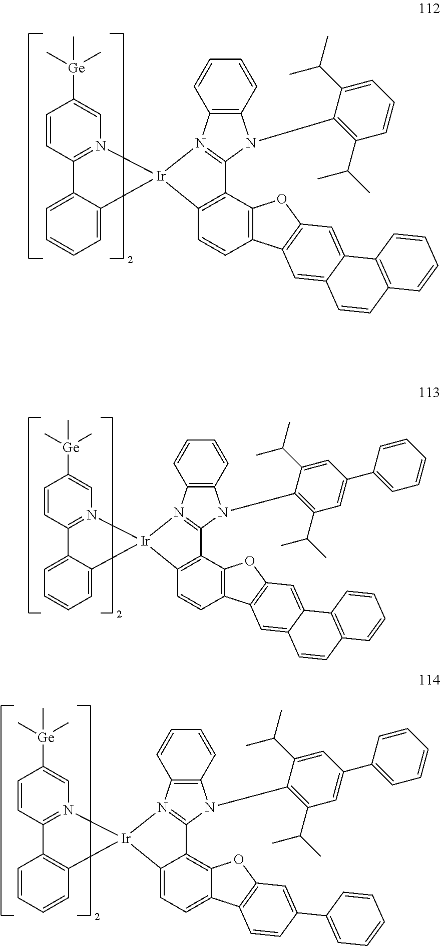

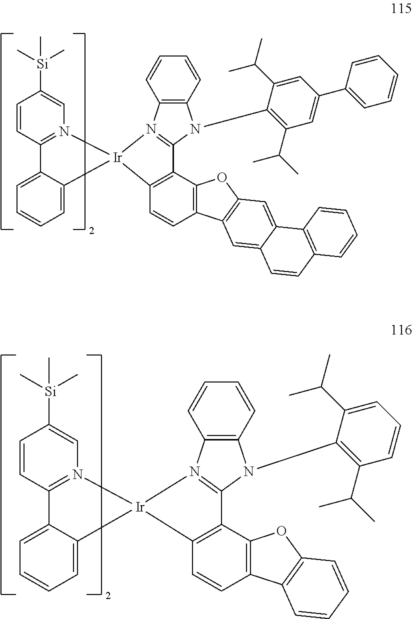

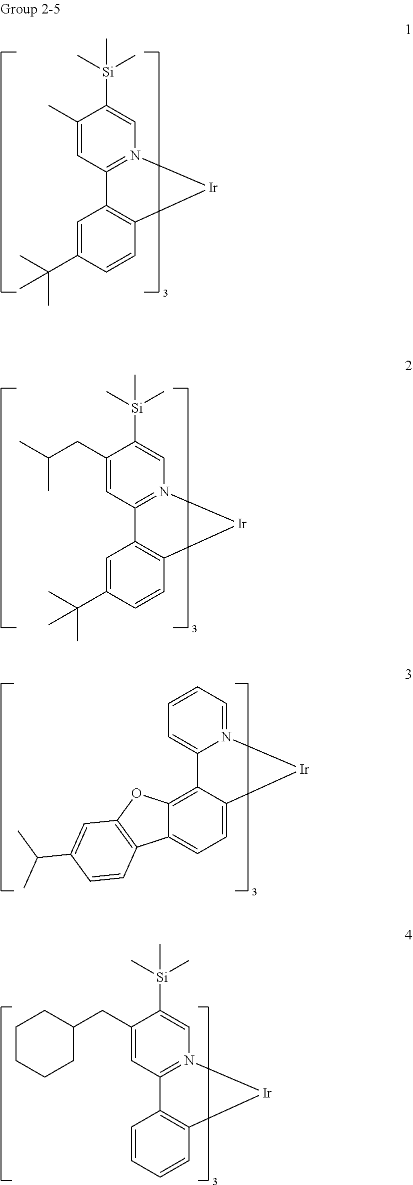

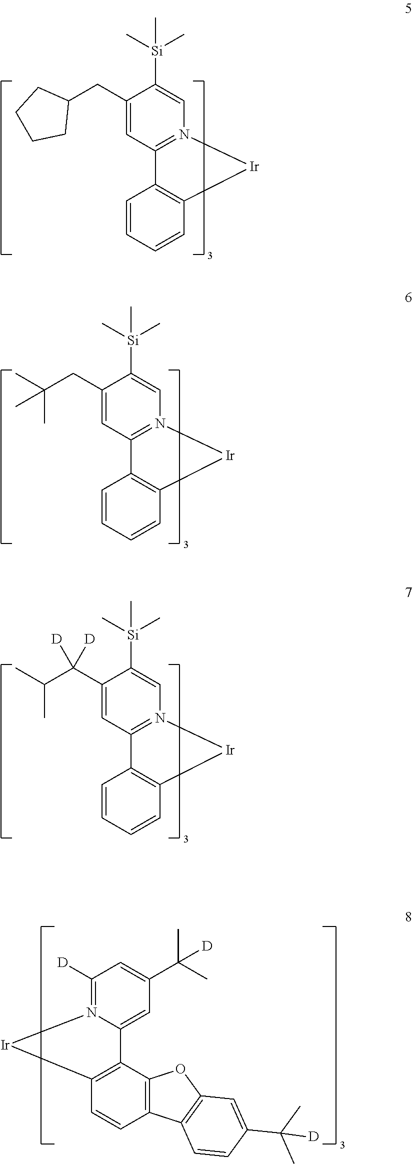

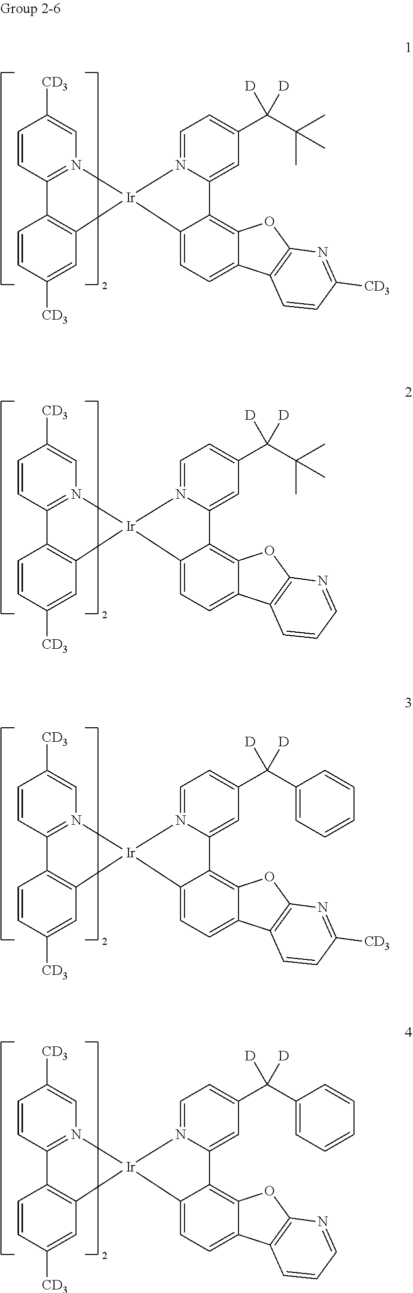

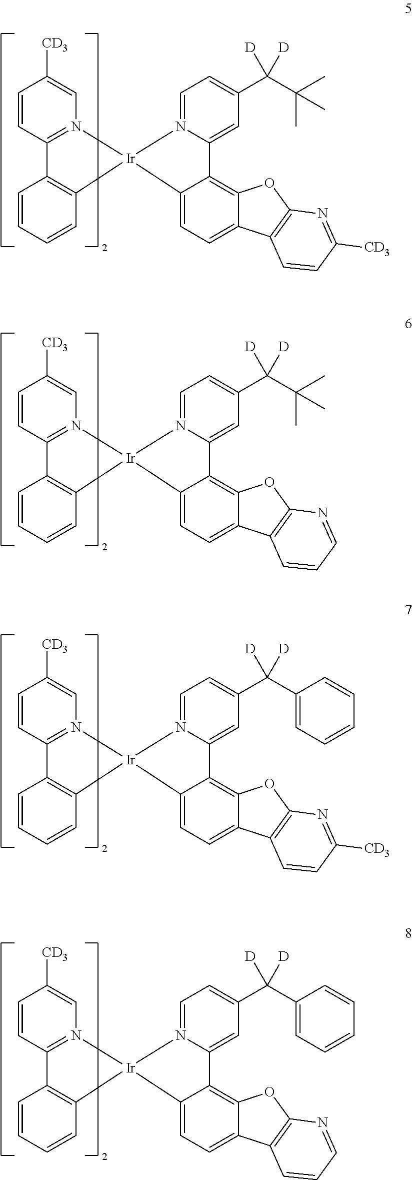

In the present specification, “Ome” refers to a methoxy group, “TMS” refers to a trimethylsilyl group, and “TMG” refers to a trimethylgermyl group.

In one or more embodiments, the iridium-containing organometallic compound may not be a compound of [Group B]:

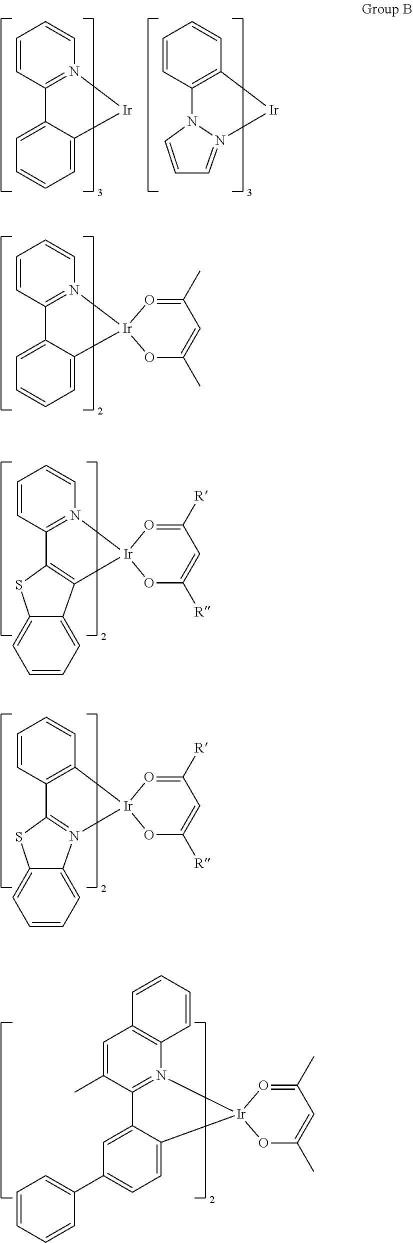

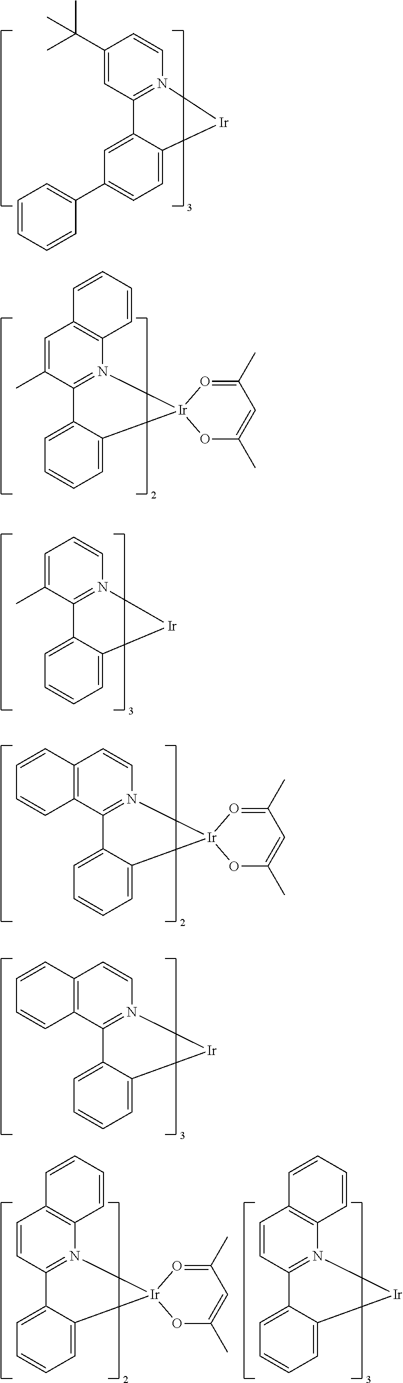

wherein R′ and R″ of [Group B] may each be an alkyl group.

The fluorescent compound
a) may not include a transition metal, and
b) may include i) boron (B), and ii) O, S, N, or a combination thereof.

In one or more embodiments, the fluorescent compound may include at least one 6-membered ring including at least one N and at least one B.

In one or more embodiments, the fluorescent compound may be a compound represented by Formula 3 or a compound represented by Formula 4:

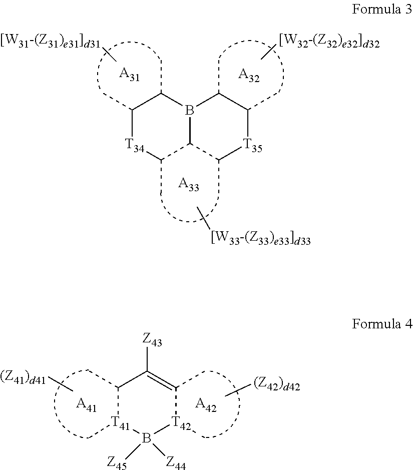

wherein, in Formulae 3 and 4,
ring A₃₁ to ring A₃₃, ring A₄₁, and ring A₄₂ may each independently be a C₅-C₃₀ carbocyclic group or a C₁-C₃₀ heterocyclic group,
T₃₄ may be O, S, or N—[W₃₄—(Z₃₄)ₑ₃₄],
T₃₅ may be O, S, or N—[W₃₅—(Z₃₅)ₑ₃₅],
T₄₁ and T₄₂ may each independently be N or C,
W₃₁ to W₃₃ are each as described in connection with W₁,
Z₃₁ to Z₃₅ and Z₄₁ to Z₄₅ are each as described in connection with Z₁,
e31 to e35 are each as described in connection with e1, and
d31 to d33 are each as described in connection with d1.

For example, ring A₃₁ to ring A₃₃, ring A₄₁, and ring A₄₂ are each as described in connection with ring A₁.

In one or more embodiments, in Formula 3, ring A₃₁ and ring A₃₂ may each be a benzene group, and ring A₃₃ may be a benzene group, a quinoline group, or an isoquinoline group.

In one or more embodiments, T₃₄ in Formula 3 may be N—[W₃₄—(Z₃₄)ₑ₃₄].

In one or more embodiments, T₃₄ in Formula 3 may be N—[W₃₄—(Z₃₄)ₑ₃₄], and Z₃₄ and ring A₃₁ and/or Z₃₄ and Z₃₁ may be bonded to each other via a single bond, or a linking group including O, S, N, B, C, or a combination thereof.

In one or more embodiments, T₃₅ in Formula 3 may be N—[W₃₅—(Z₃₅)ₑ₃₅].

In one or more embodiments, T₃₅ in Formula 3 may be N—[W₃₅—(Z₃₅)ₑ₃₅], and Z₃₅ and ring A₃₂ and/or Z₃₅ and Z₃₂ may be bonded to each other via a single bond, or a linking group including O, S, N, B, C, or a combination thereof.

In one or more embodiments, ring A₄₁ and ring A₄₂ in Formula 4 may each be a pyrrole group. For example, T₄₁ and T₄₂ may each be N.

For example, the fluorescent compound may be selected from compounds of [Group 3] and [Group 4]:

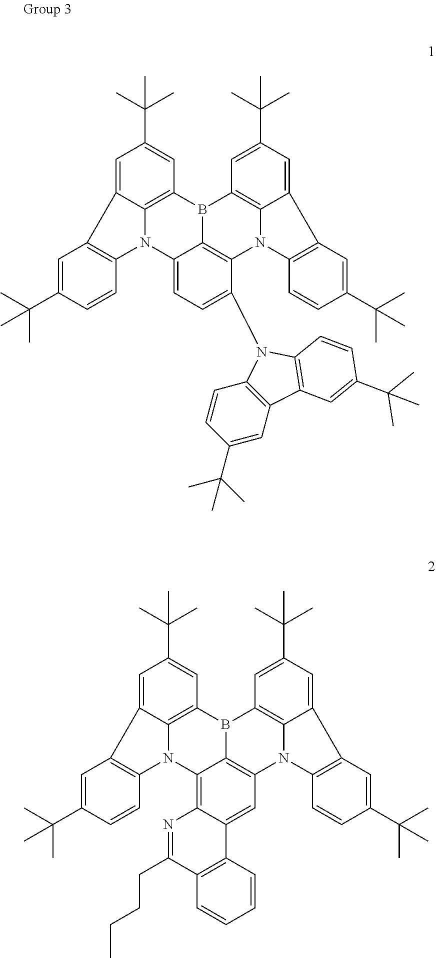

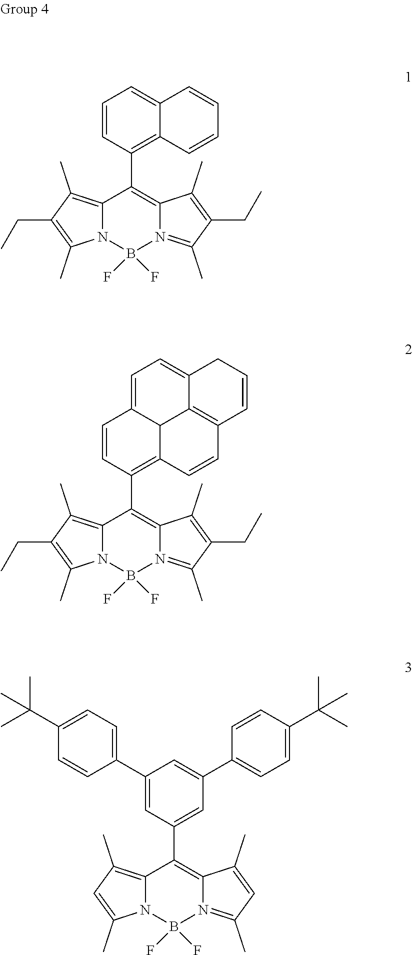

A weight ratio of the first compound to the second compound in the composition of the first compound and the second compound may be in range of about 90:10 to about 10:90, about 80:20 to about 20:80, about 70:30 to about 30:70, or about 60:40 to about 40:60.

### Description of Matrix Material

The matrix material may be, for example, a host of an emission layer among materials for an organic light-emitting device.

In one or more embodiments, the matrix material may consist of only one compound (for example, a hole-transporting compound, an electron-transporting compound, or a bipolar compound).

In one or more embodiments, the matrix material may include a first host and a second host, and the first host and the second host may be different from each other.

The first host and the second host may each include a hole-transporting compound, an electron-transporting compound, a bipolar compound, or a combination thereof.

For example, the first host and the second host may each include a hole-transporting compound and an electron-transporting compound, and the hole-transporting compound and the electron-transporting compound may be different from each other.

In one or more embodiments, the hole-transporting compound may include at least one π electron-rich C₃-C₆₀ cyclic group (for example, a carbazole group, an indolocarbazole group, a benzene group, or the like), and may not include an electron-transporting group. Examples of the electron-transporting group may include a cyano group, a fluoro group, a π electron-deficient nitrogen-containing C₁-C₆₀ cyclic group, a phosphine oxide group, a sulfoxide group, and the like.

In one or more embodiments, the electron-transporting compound may be a compound including at least one electron-transporting group. The electron-transporting group may be a cyano group, a fluoro group, a π electron-deficient nitrogen-containing C₁-C₆₀ cyclic group, a phosphine oxide group, a sulfoxide group, or a combination thereof.

In one or more embodiments, the hole-transporting compound may be at least one of Compounds H1-1 to H1-72 of Group 5-1 and Compounds H1-1 to H1-20 of Group 5-2:

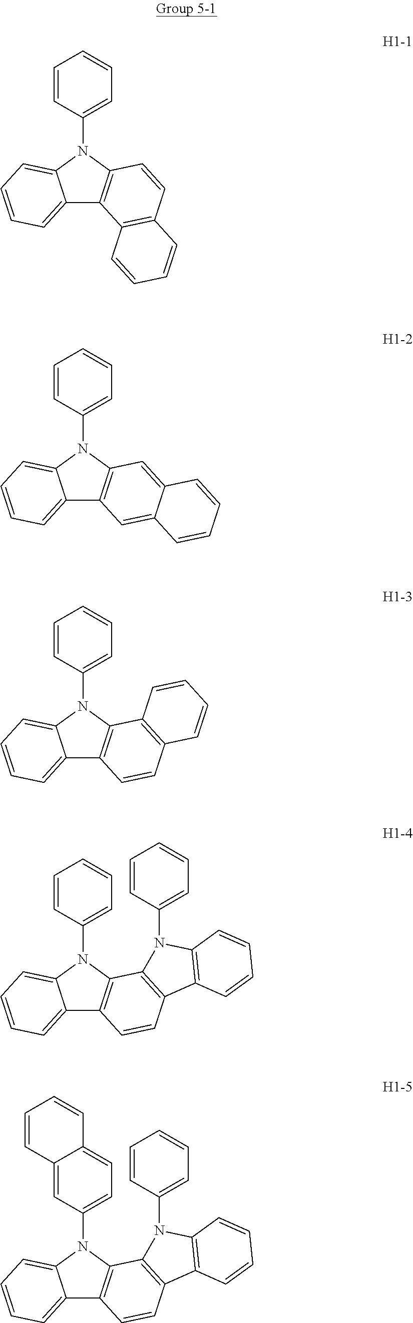 [SMILES: c1ccc(-n2c3ccccc3c3c4ccccc4ccc32)cc1 ; c1ccc(-n2c3ccccc3c3cc4ccccc4cc32)cc1 ; c1ccc(-n2c3ccccc3c3ccc4ccccc4c32)cc1 ; c1ccc(-n2c3ccccc3c3ccc4c5ccccc5n(-c5ccccc5)c4c32)cc1 ; c1ccc(-n2c3ccccc3c3ccc4c5ccccc5n(-c5ccc6ccccc6c5)c4c32)cc1]

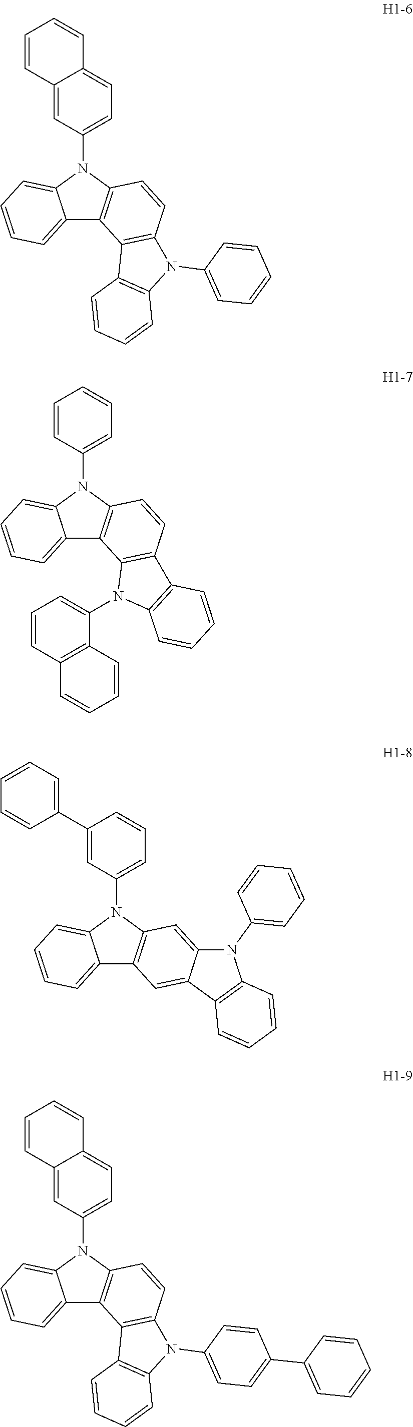 [SMILES: c1ccc(-n2c3ccccc3c3c4c5ccccc5n(-c5ccc6ccccc6c5)c4ccc32)cc1 ; c1ccc(-n2c3ccccc3c3c2ccc2c4ccccc4n(-c4cccc5ccccc45)c23)cc1 ; c1ccc(-c2cccc(-n3c4ccccc4c4cc5c6ccccc6n(-c6ccccc6)c5cc43)c2)cc1 ; c1ccc(-c2ccc(-n3c4ccccc4c4c5c6ccccc6n(-c6ccc7ccccc7c6)c5ccc43)cc2)cc1]

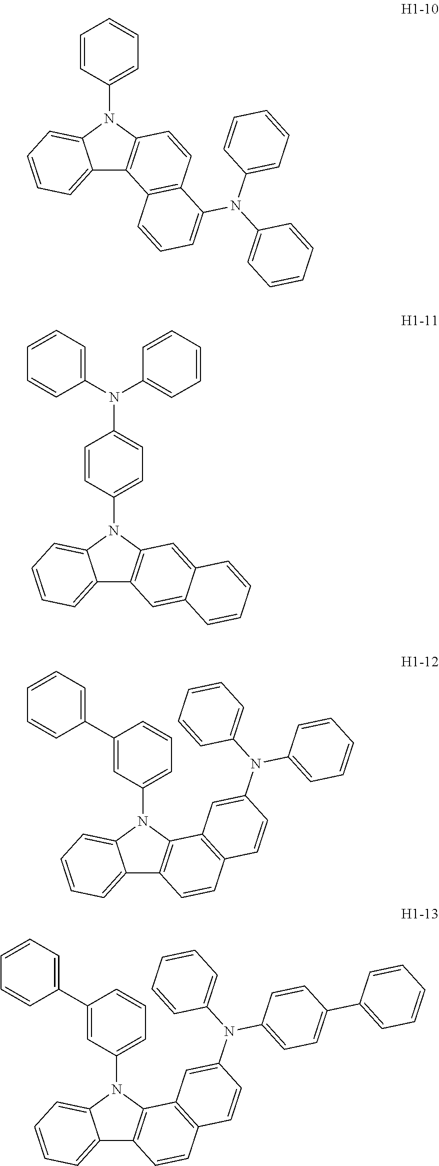 [SMILES: c1ccc(N(c2ccccc2)c2cccc3c2ccc2c3c3ccccc3n2-c2ccccc2)cc1 ; c1ccc(N(c2ccccc2)c2ccc(-n3c4ccccc4c4cc5ccccc5cc43)cc2)cc1 ; c1ccc(-c2cccc(-n3c4ccccc4c4ccc5ccc(N(c6ccccc6)c6ccccc6)cc5c43)c2)cc1 ; c1ccc(-c2ccc(N(c3ccccc3)c3ccc4ccc5c6ccccc6n(-c6cccc(-c7ccccc7)c6)c5c4c3)cc2)cc1]

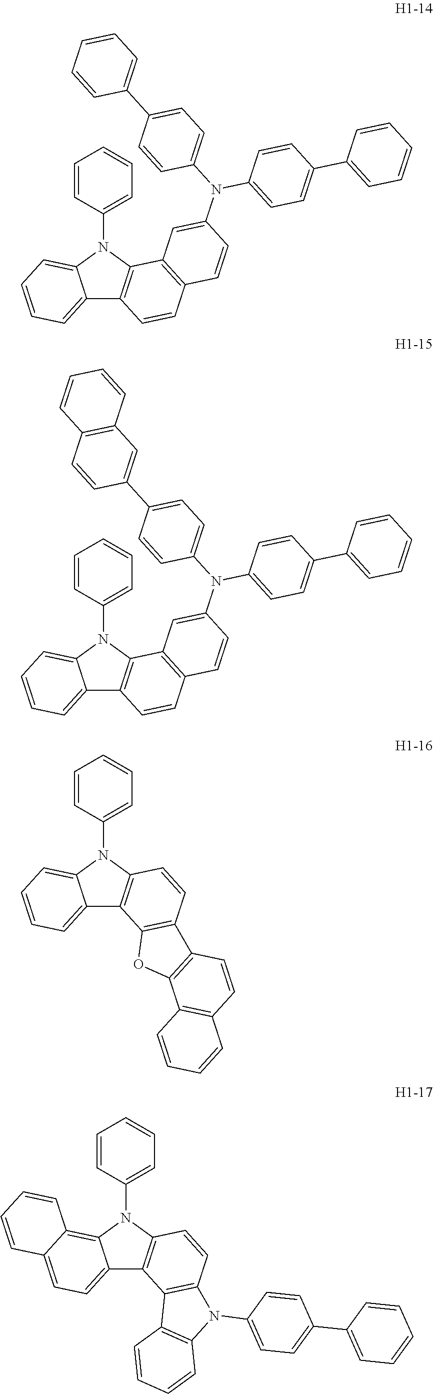 [SMILES: c1ccc(-c2ccc(N(c3ccc(-c4ccccc4)cc3)c3ccc4ccc5c6ccccc6n(-c6ccccc6)c5c4c3)cc2)cc1 ; c1ccc(-c2ccc(N(c3ccc(-c4ccc5ccccc5c4)cc3)c3ccc4ccc5c6ccccc6n(-c6ccccc6)c5c4c3)cc2)cc1 ; c1ccc(-n2c3ccccc3c3c4oc5c6ccccc6ccc5c4ccc32)cc1 ; c1ccc(-c2ccc(-n3c4ccccc4c4c5c6ccc7ccccc7c6n(-c6ccccc6)c5ccc43)cc2)cc1]

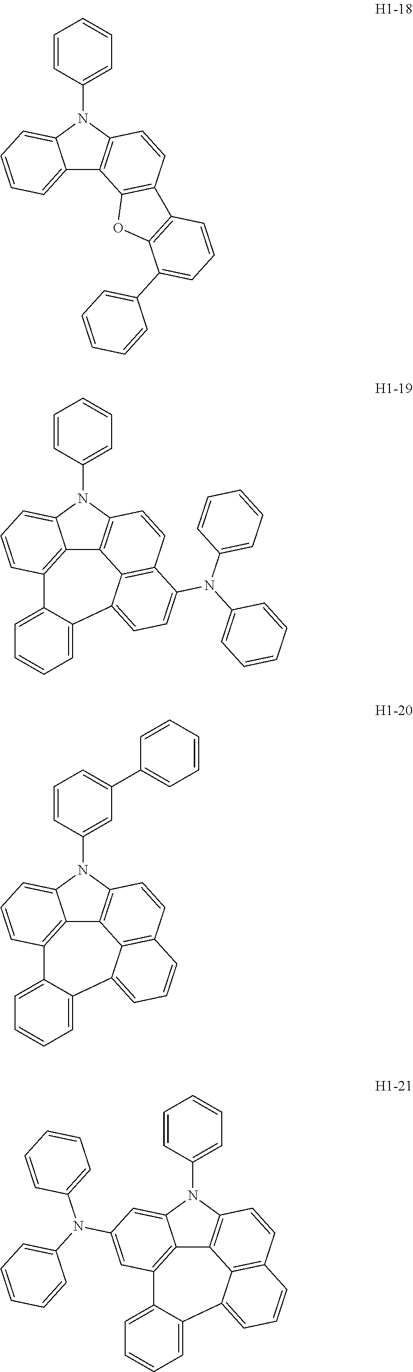 [SMILES: c1ccc(-c2cccc3c2oc2c3ccc3c2c2ccccc2n3-c2ccccc2)cc1 ; c1ccc(N(c2ccccc2)c2ccc3c4c2ccc2c4c4c(cccc4n2-c2ccccc2)-c2ccccc2-3)cc1 ; c1ccc(-c2cccc(-n3c4cccc5c4c4c6c(cccc6ccc43)-c3ccccc3-5)c2)cc1 ; c1ccc(N(c2ccccc2)c2cc3c4c5c6c(cccc6ccc5n(-c5ccccc5)c4c2)-c2ccccc2-3)cc1]

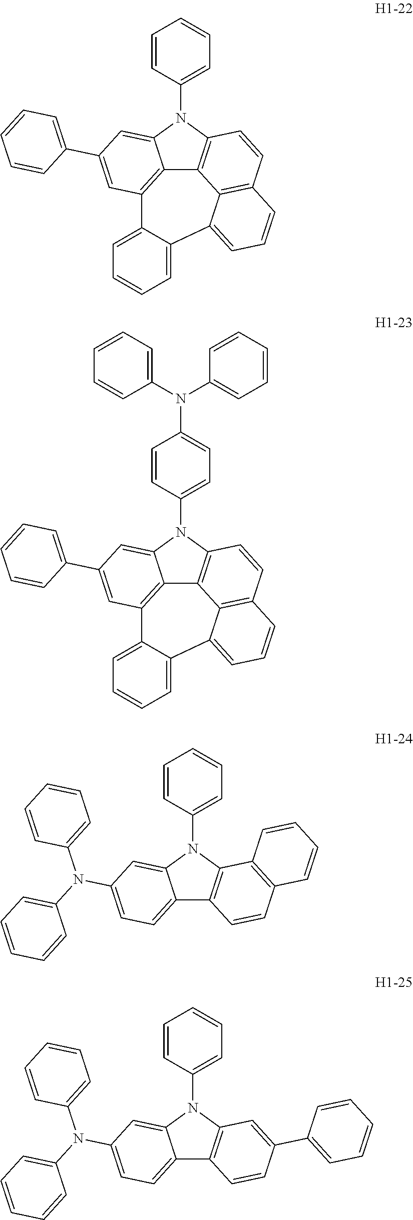

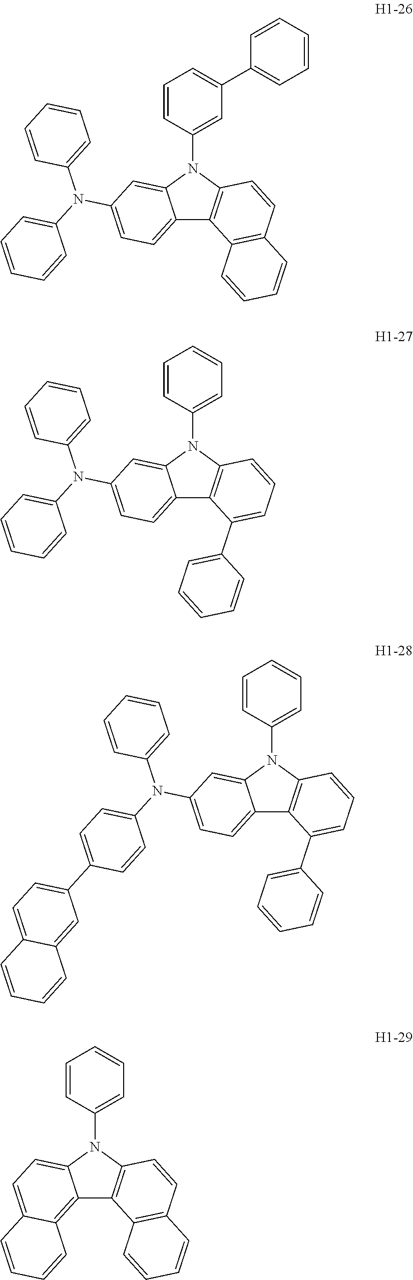 [SMILES: c1ccc(-c2cccc(-n3c4cc(N(c5ccccc5)c5ccccc5)ccc4c4c5ccccc5ccc43)c2)cc1 ; c1ccc(-c2cccc3c2c2ccc(N(c4ccccc4)c4ccccc4)cc2n3-c2ccccc2)cc1 ; c1ccc(-c2cccc3c2c2ccc(N(c4ccccc4)c4ccc(-c5ccc6ccccc6c5)cc4)cc2n3-c2ccccc2)cc1 ; c1ccc(-n2c3ccc4ccccc4c3c3c4ccccc4ccc32)cc1]

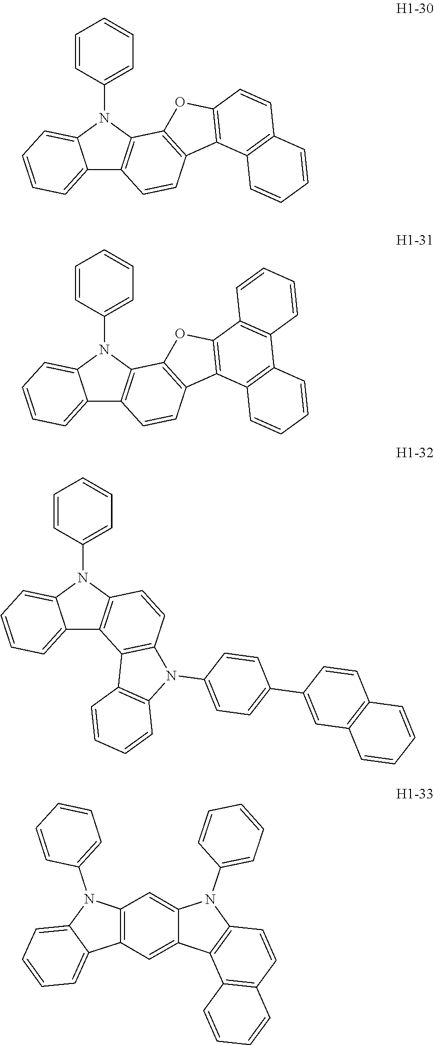 [SMILES: c1ccc(-n2c3ccccc3c3ccc4c(oc5ccc6ccccc6c54)c32)cc1 ; c1ccc(-n2c3ccccc3c3ccc4c(oc5c6ccccc6c6ccccc6c45)c32)cc1 ; c1ccc(-n2c3ccccc3c3c4c5ccccc5n(-c5ccc(-c6ccc7ccccc7c6)cc5)c4ccc32)cc1 ; c1ccc(-n2c3ccccc3c3cc4c5c6ccccc6ccc5n(-c5ccccc5)c4cc32)cc1]

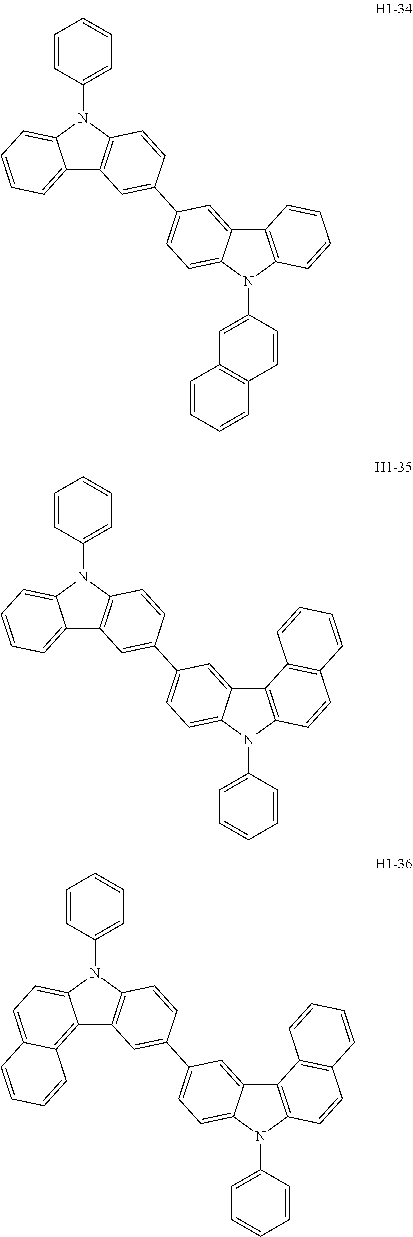 [SMILES: c1ccc(-n2c3ccccc3c3cc(-c4ccc5c(c4)c4ccccc4n5-c4ccc5ccccc5c4)ccc32)cc1 ; c1ccc(-n2c3ccccc3c3cc(-c4ccc5c(c4)c4c6ccccc6ccc4n5-c4ccccc4)ccc32)cc1 ; c1ccc(-n2c3ccc(-c4ccc5c(c4)c4c6ccccc6ccc4n5-c4ccccc4)cc3c3c4ccccc4ccc32)cc1]

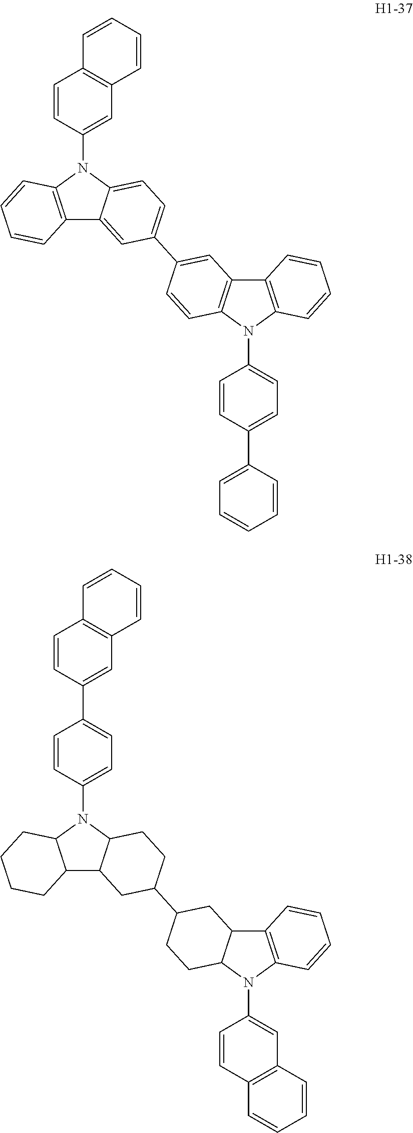 [SMILES: c1ccc(-c2ccc(-n3c4ccccc4c4cc(-c5ccc6c(c5)c5ccccc5n6-c5ccc6ccccc6c5)ccc43)cc2)cc1 ; c1ccc2c(c1)C1CC(C3CCC4C(C3)C3CCCCC3N4c3ccc(-c4ccc5ccccc5c4)cc3)CCC1N2c1ccc2ccccc2c1]

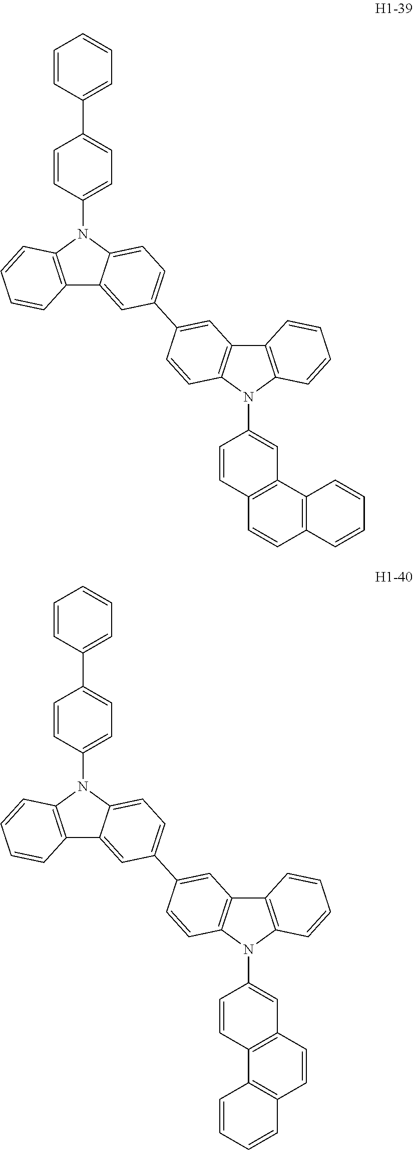 [SMILES: c1ccc(-c2ccc(-n3c4ccccc4c4cc(-c5ccc6c(c5)c5ccccc5n6-c5ccc6ccc7ccccc7c6c5)ccc43)cc2)cc1 ; c1ccc(-c2ccc(-n3c4ccccc4c4cc(-c5ccc6c(c5)c5ccccc5n6-c5ccc6c(ccc7ccccc76)c5)ccc43)cc2)cc1]

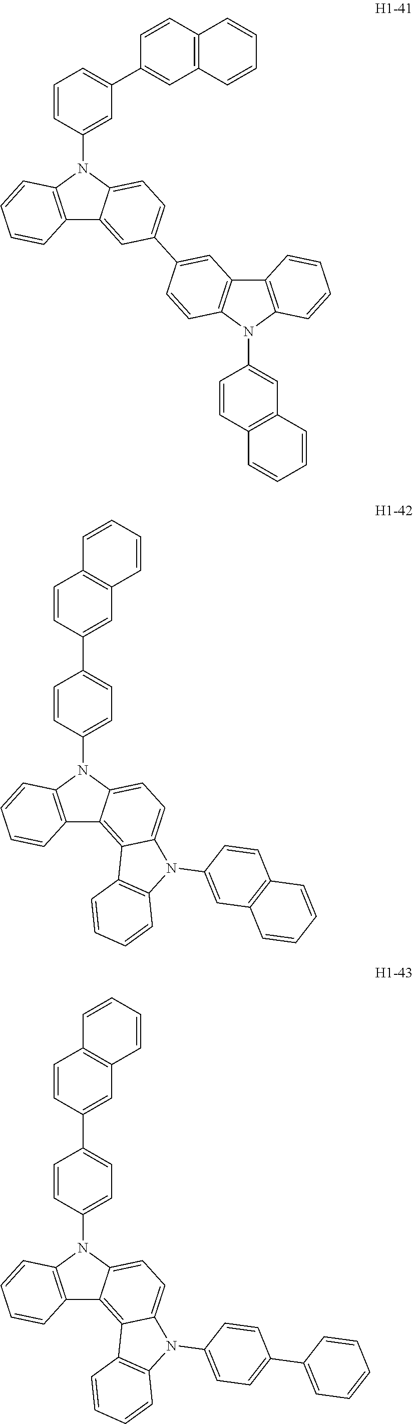 [SMILES: c1cc(-c2ccc3ccccc3c2)cc(-n2c3ccccc3c3cc(-c4ccc5c(c4)c4ccccc4n5-c4ccc5ccccc5c4)ccc32)c1 ; c1ccc2cc(-c3ccc(-n4c5ccccc5c5c6c7ccccc7n(-c7ccc8ccccc8c7)c6ccc54)cc3)ccc2c1 ; c1ccc(-c2ccc(-n3c4ccccc4c4c5c6ccccc6n(-c6ccc(-c7ccc8ccccc8c7)cc6)c5ccc43)cc2)cc1]

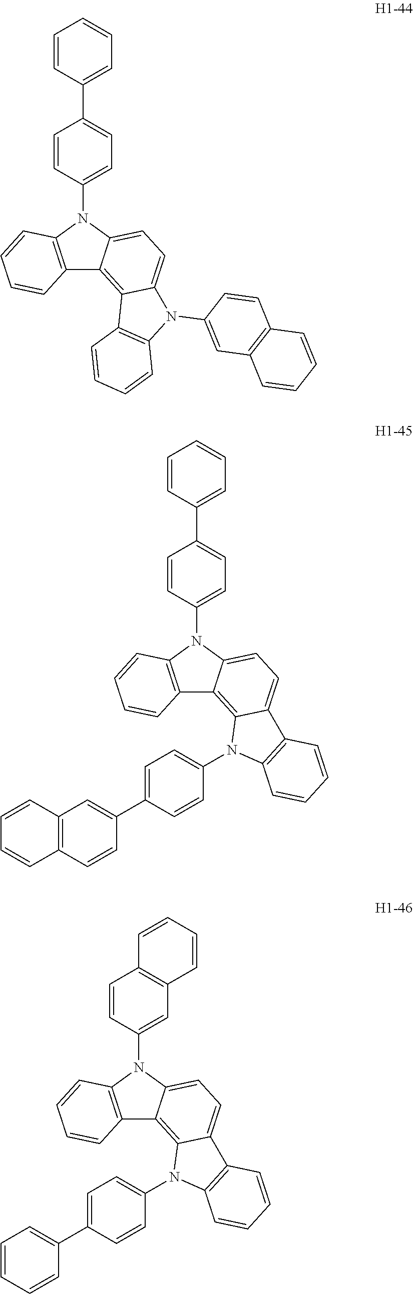 [SMILES: c1ccc(-c2ccc(-n3c4ccccc4c4c5c6ccccc6n(-c6ccc7ccccc7c6)c5ccc43)cc2)cc1 ; c1ccc(-c2ccc(-n3c4ccccc4c4c3ccc3c5ccccc5n(-c5ccc(-c6ccc7ccccc7c6)cc5)c34)cc2)cc1 ; c1ccc(-c2ccc(-n3c4ccccc4c4ccc5c(c6ccccc6n5-c5ccc6ccccc6c5)c43)cc2)cc1]

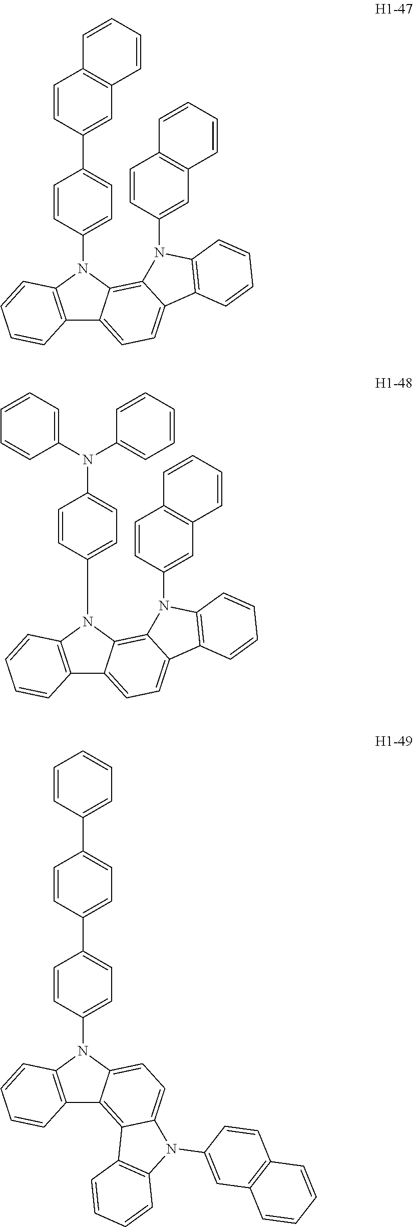 [SMILES: c1ccc2cc(-c3ccc(-n4c5ccccc5c5ccc6c7ccccc7n(-c7ccc8ccccc8c7)c6c54)cc3)ccc2c1 ; c1ccc(N(c2ccccc2)c2ccc(-n3c4ccccc4c4ccc5c6ccccc6n(-c6ccc7ccccc7c6)c5c43)cc2)cc1 ; c1ccc(-c2ccc(-c3ccc(-n4c5ccccc5c5c6c7ccccc7n(-c7ccc8ccccc8c7)c6ccc54)cc3)cc2)cc1]

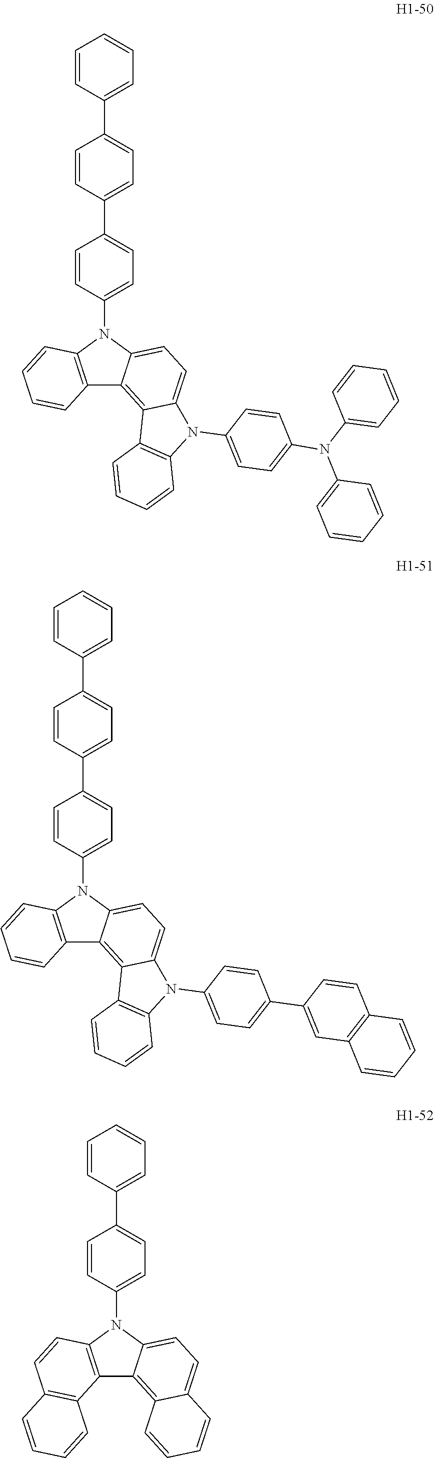 [SMILES: c1ccc(-c2ccc(-c3ccc(-n4c5ccccc5c5c6c7ccccc7n(-c7ccc(N(c8ccccc8)c8ccccc8)cc7)c6ccc54)cc3)cc2)cc1 ; c1ccc(-c2ccc(-c3ccc(-n4c5ccccc5c5c6c7ccccc7n(-c7ccc(-c8ccc9ccccc9c8)cc7)c6ccc54)cc3)cc2)cc1 ; c1ccc(-c2ccc(-n3c4ccc5ccccc5c4c4c5ccccc5ccc43)cc2)cc1]

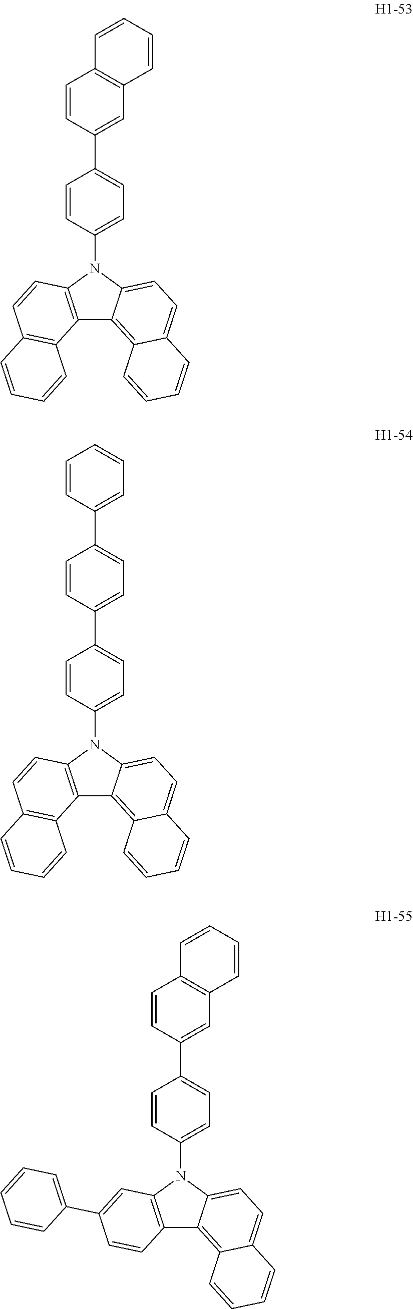 [SMILES: c1ccc2cc(-c3ccc(-n4c5ccc6ccccc6c5c5c6ccccc6ccc54)cc3)ccc2c1 ; c1ccc(-c2ccc(-c3ccc(-n4c5ccc6ccccc6c5c5c6ccccc6ccc54)cc3)cc2)cc1 ; c1ccc(-c2ccc3c4c5ccccc5ccc4n(-c4ccc(-c5ccc6ccccc6c5)cc4)c3c2)cc1]

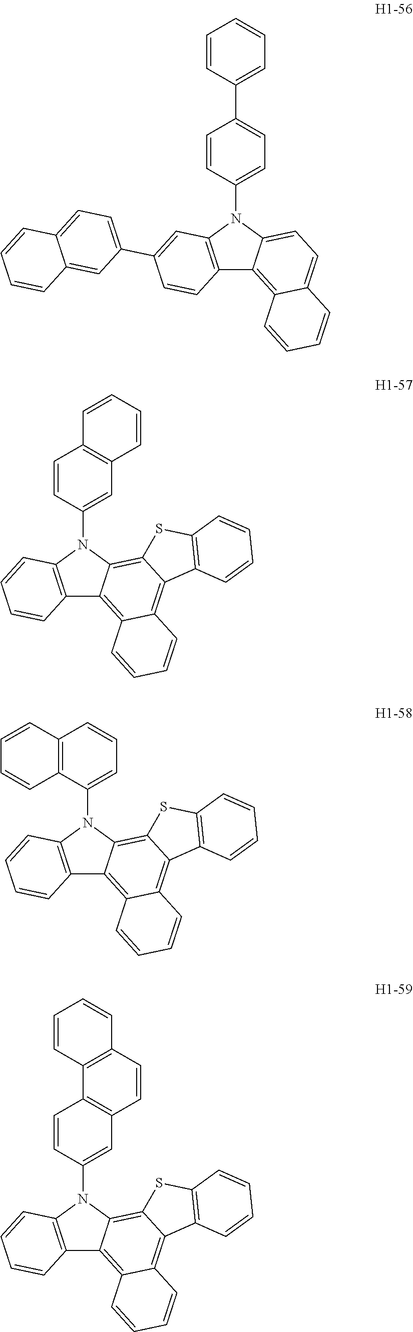 [SMILES: c1ccc(-c2ccc(-n3c4cc(-c5ccc6ccccc6c5)ccc4c4c5ccccc5ccc43)cc2)cc1 ; c1ccc2cc(-n3c4ccccc4c4c5ccccc5c5c6ccccc6sc5c43)ccc2c1 ; c1ccc2c(-n3c4ccccc4c4c5ccccc5c5c6ccccc6sc5c43)cccc2c1 ; c1ccc2c(c1)ccc1cc(-n3c4ccccc4c4c5ccccc5c5c6ccccc6sc5c43)ccc12]

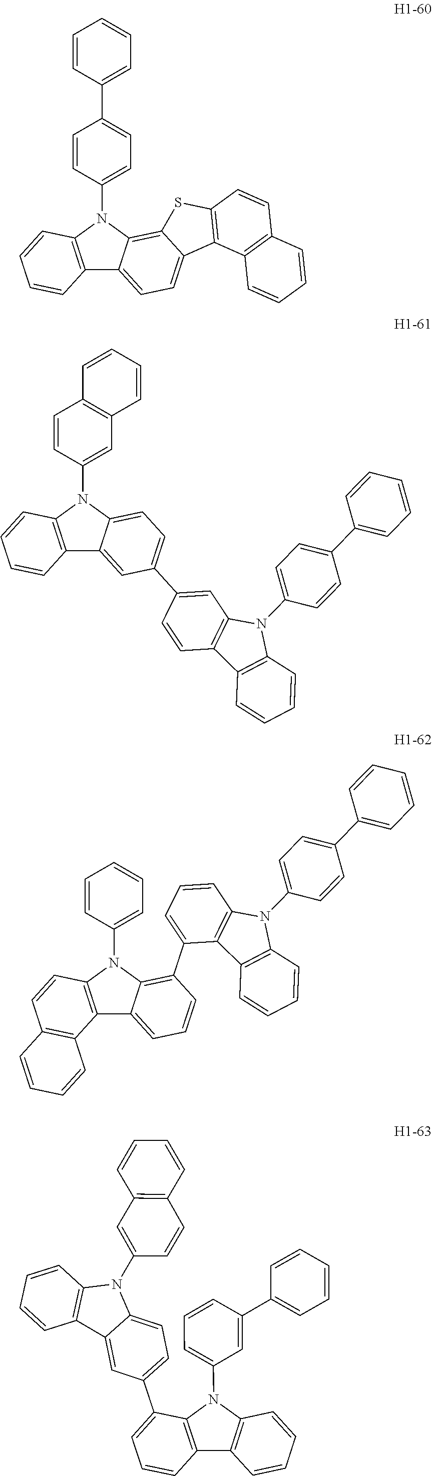 [SMILES: c1ccc(-c2ccc(-n3c4ccccc4c4ccc5c(sc6ccc7ccccc7c65)c43)cc2)cc1 ; c1ccc(-c2ccc(-n3c4ccccc4c4ccc(-c5ccc6c(c5)c5ccccc5n6-c5ccc6ccccc6c5)cc43)cc2)cc1 ; c1ccc(-c2ccc(-n3c4ccccc4c4c(-c5cccc6c7c8ccccc8ccc7n(-c7ccccc7)c56)cccc43)cc2)cc1 ; c1ccc(-c2cccc(-n3c4ccccc4c4cccc(-c5ccc6c(c5)c5ccccc5n6-c5ccc6ccccc6c5)c43)c2)cc1]

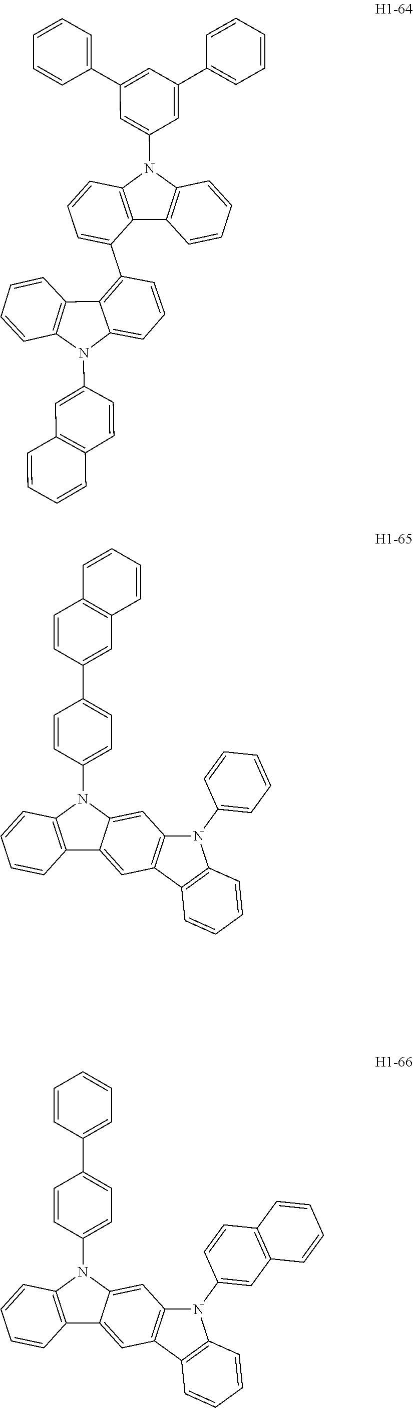 [SMILES: c1ccc(-c2cc(-c3ccccc3)cc(-n3c4ccccc4c4c(-c5cccc6c5c5ccccc5n6-c5ccc6ccccc6c5)cccc43)c2)cc1 ; c1ccc(-n2c3ccccc3c3cc4c5ccccc5n(-c5ccc(-c6ccc7ccccc7c6)cc5)c4cc32)cc1 ; c1ccc(-c2ccc(-n3c4ccccc4c4cc5c6ccccc6n(-c6ccc7ccccc7c6)c5cc43)cc2)cc1]

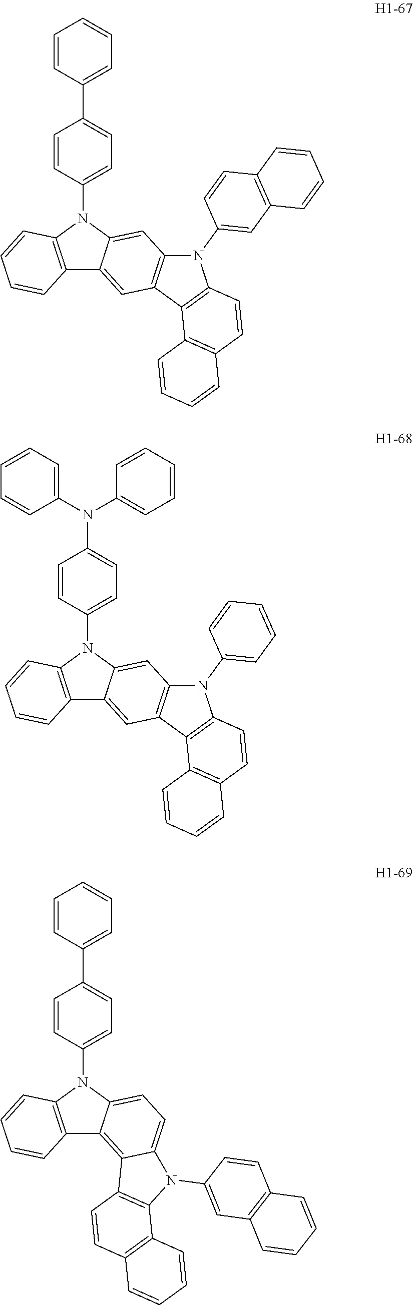 [SMILES: c1ccc(-c2ccc(-n3c4ccccc4c4cc5c6c7ccccc7ccc6n(-c6ccc7ccccc7c6)c5cc43)cc2)cc1 ; c1ccc(N(c2ccccc2)c2ccc(-n3c4ccccc4c4cc5c6c7ccccc7ccc6n(-c6ccccc6)c5cc43)cc2)cc1 ; c1ccc(-c2ccc(-n3c4ccccc4c4c5c6ccc7ccccc7c6n(-c6ccc7ccccc7c6)c5ccc43)cc2)cc1]

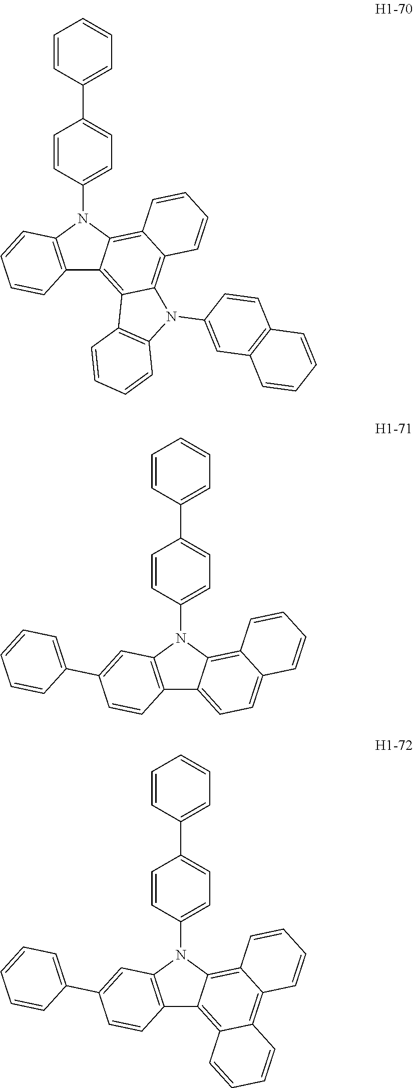 [SMILES: c1ccc(-c2ccc(-n3c4ccccc4c4c5c6ccccc6n(-c6ccc7ccccc7c6)c5c5ccccc5c43)cc2)cc1 ; c1ccc(-c2ccc(-n3c4cc(-c5ccccc5)ccc4c4ccc5ccccc5c43)cc2)cc1 ; c1ccc(-c2ccc(-n3c4cc(-c5ccccc5)ccc4c4c5ccccc5c5ccccc5c43)cc2)cc1]

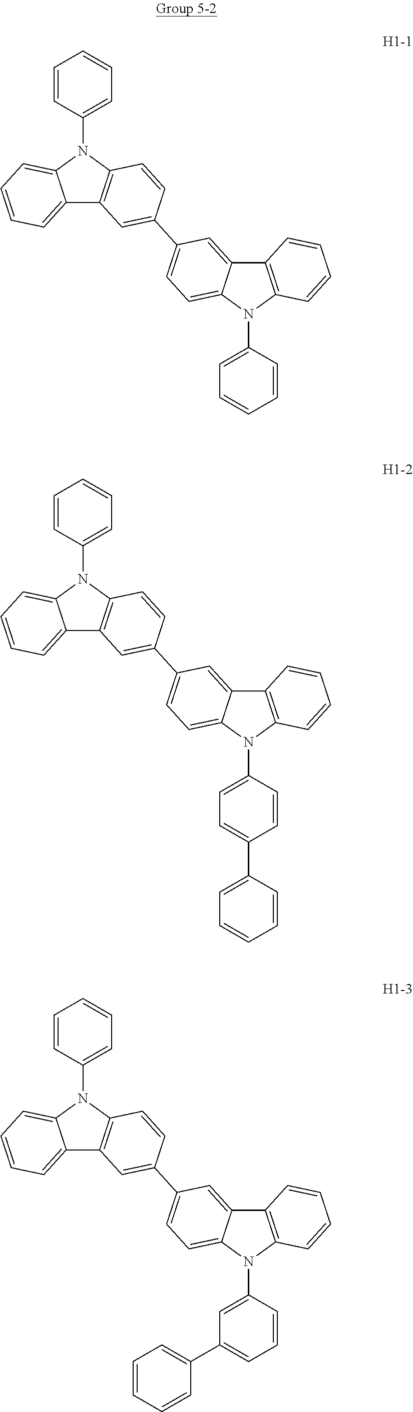 [SMILES: c1ccc(-n2c3ccccc3c3cc(-c4ccc5c(c4)c4ccccc4n5-c4ccccc4)ccc32)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cccc(-n3c4ccccc4c4cc(-c5ccc6c(c5)c5ccccc5n6-c5ccccc5)ccc43)c2)cc1]

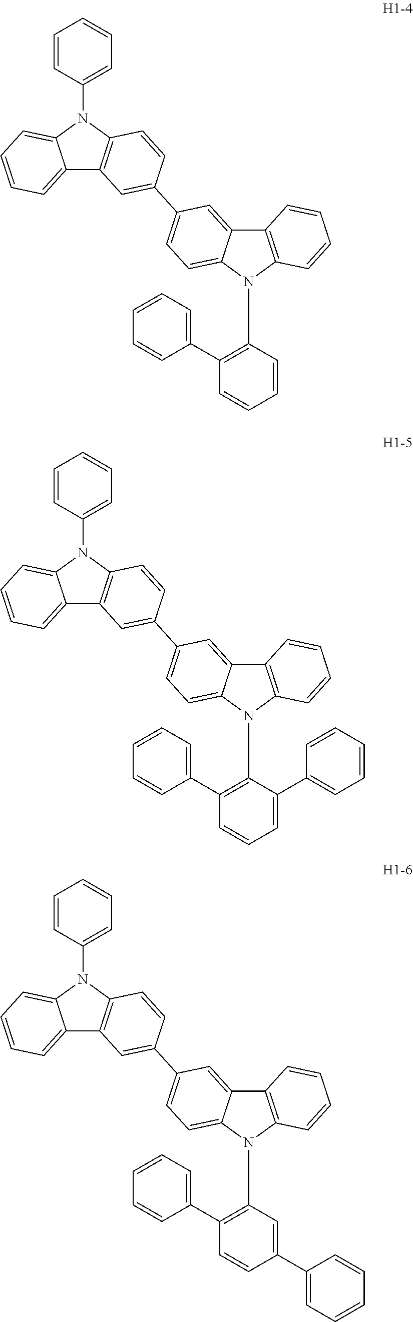 [SMILES: c1ccc(-c2ccccc2-n2c3ccccc3c3cc(-c4ccc5c(c4)c4ccccc4n5-c4ccccc4)ccc32)cc1 ; c1ccc(-c2cccc(-c3ccccc3)c2-n2c3ccccc3c3cc(-c4ccc5c(c4)c4ccccc4n5-c4ccccc4)ccc32)cc1 ; c1ccc(-c2ccc(-c3ccccc3)c(-n3c4ccccc4c4cc(-c5ccc6c(c5)c5ccccc5n6-c5ccccc5)ccc43)c2)cc1]

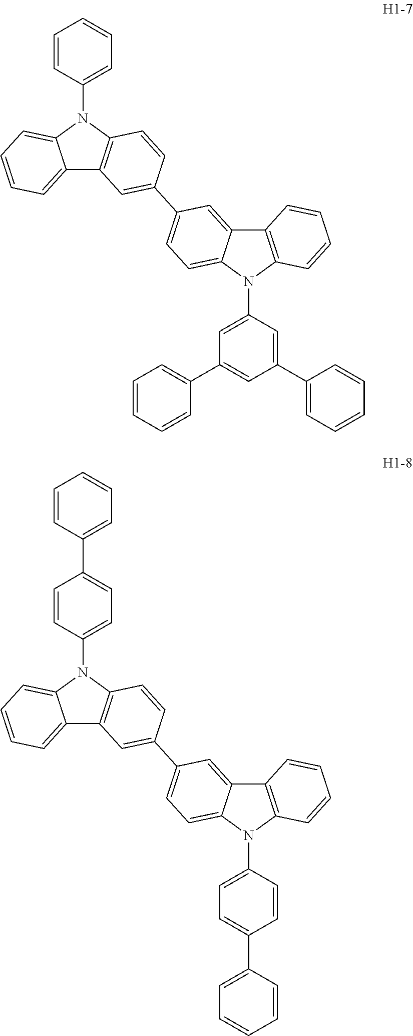 [SMILES: c1ccc(-c2cc(-c3ccccc3)cc(-n3c4ccccc4c4cc(-c5ccc6c(c5)c5ccccc5n6-c5ccccc5)ccc43)c2)cc1 ; c1ccc(-c2ccc(-n3c4ccccc4c4cc(-c5ccc6c(c5)c5ccccc5n6-c5ccc(-c6ccccc6)cc5)ccc43)cc2)cc1]

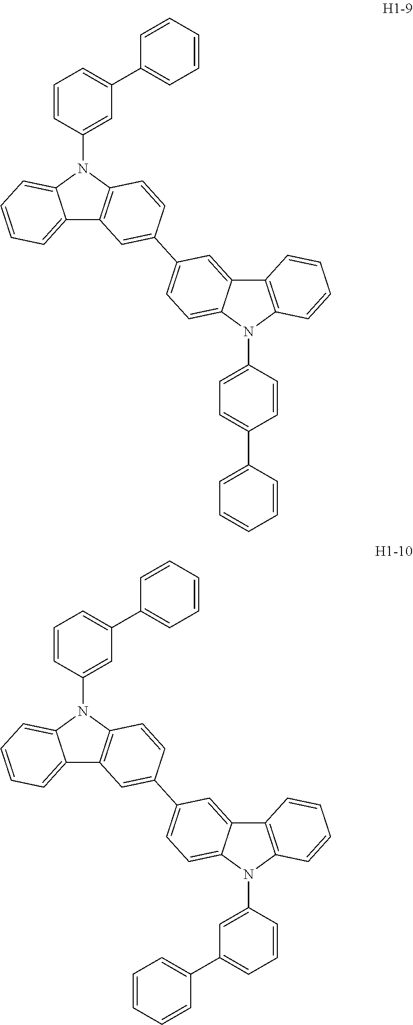 [SMILES: c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2cccc(-n3c4ccccc4c4cc(-c5ccc6c(c5)c5ccccc5n6-c5cccc(-c6ccccc6)c5)ccc43)c2)cc1]

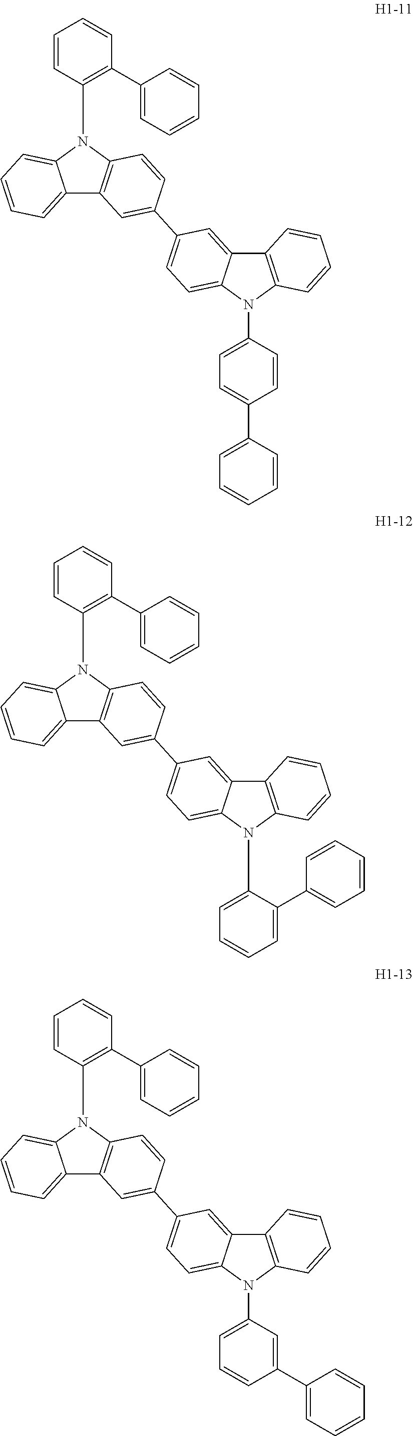 [SMILES: c1ccc(-c2ccc(-n3c4ccccc4c4cc(-c5ccc6c(c5)c5ccccc5n6-c5ccccc5-c5ccccc5)ccc43)cc2)cc1 ; c1ccc(-c2ccccc2-n2c3ccccc3c3cc(-c4ccc5c(c4)c4ccccc4n5-c4ccccc4-c4ccccc4)ccc32)cc1 ; c1ccc(-c2cccc(-n3c4ccccc4c4cc(-c5ccc6c(c5)c5ccccc5n6-c5ccccc5-c5ccccc5)ccc43)c2)cc1]

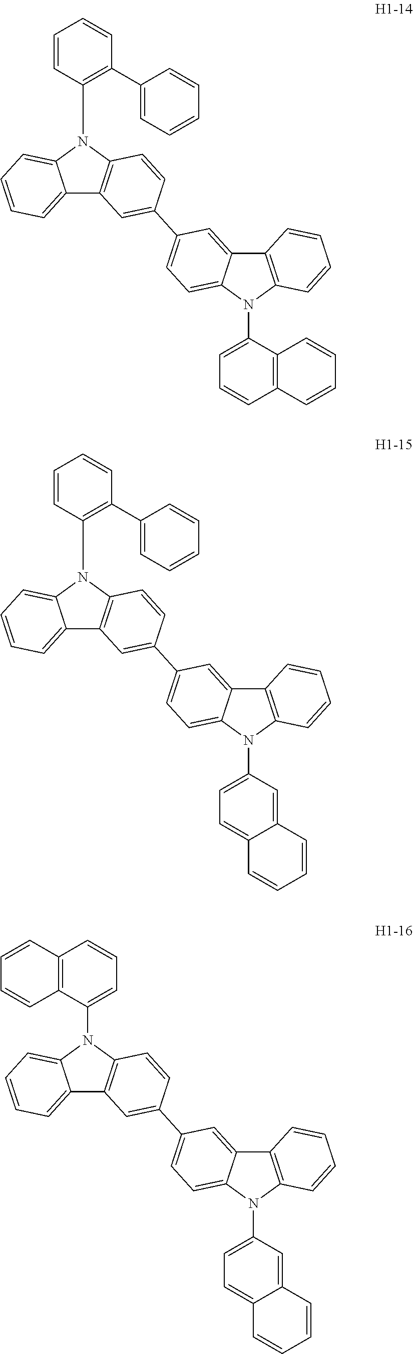 [SMILES: c1ccc(-c2ccccc2-n2c3ccccc3c3cc(-c4ccc5c(c4)c4ccccc4n5-c4cccc5ccccc45)ccc32)cc1 ; c1ccc(-c2ccccc2-n2c3ccccc3c3cc(-c4ccc5c(c4)c4ccccc4n5-c4ccc5ccccc5c4)ccc32)cc1 ; c1ccc2cc(-n3c4ccccc4c4cc(-c5ccc6c(c5)c5ccccc5n6-c5cccc6ccccc56)ccc43)ccc2c1]

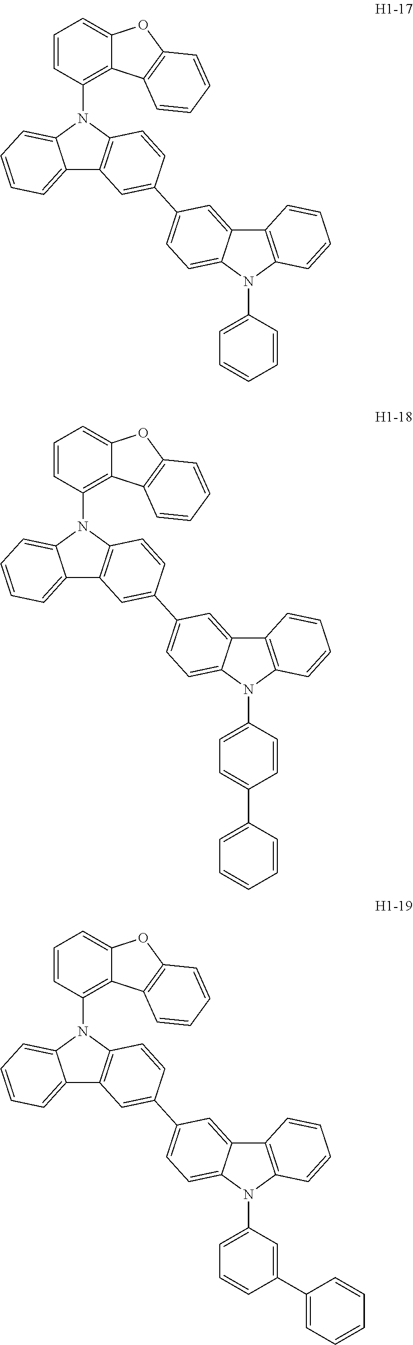 [SMILES: c1ccc(-n2c3ccccc3c3cc(-c4ccc5c(c4)c4ccccc4n5-c4cccc5oc6ccccc6c45)ccc32)cc1 ; c1ccc(-c2ccc(-n3c4ccccc4c4cc(-c5ccc6c(c5)c5ccccc5n6-c5cccc6oc7ccccc7c56)ccc43)cc2)cc1 ; c1ccc(-c2cccc(-n3c4ccccc4c4cc(-c5ccc6c(c5)c5ccccc5n6-c5cccc6oc7ccccc7c56)ccc43)c2)cc1]

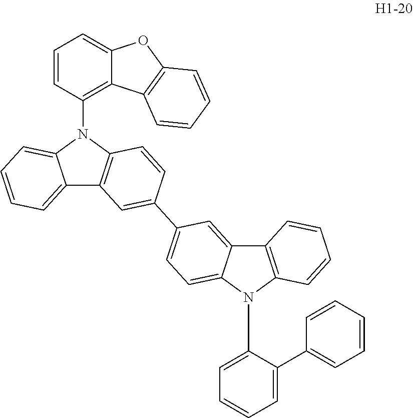 [SMILES: c1ccc(-c2ccccc2-n2c3ccccc3c3cc(-c4ccc5c(c4)c4ccccc4n5-c4cccc5oc6ccccc6c45)ccc32)cc1]

In one or more embodiments, the electron-transporting compound may be at least one of Compounds E1-1 to E1-62:

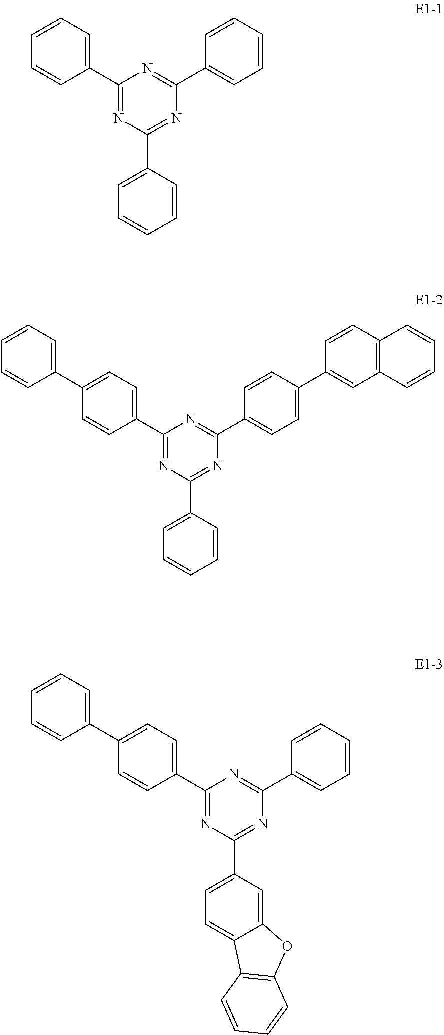 [SMILES: c1ccc(-c2nc(-c3ccccc3)nc(-c3ccccc3)n2)cc1 ; c1ccc(-c2ccc(-c3nc(-c4ccccc4)nc(-c4ccc(-c5ccc6ccccc6c5)cc4)n3)cc2)cc1 ; c1ccc(-c2ccc(-c3nc(-c4ccccc4)nc(-c4ccc5c(c4)oc4ccccc45)n3)cc2)cc1]

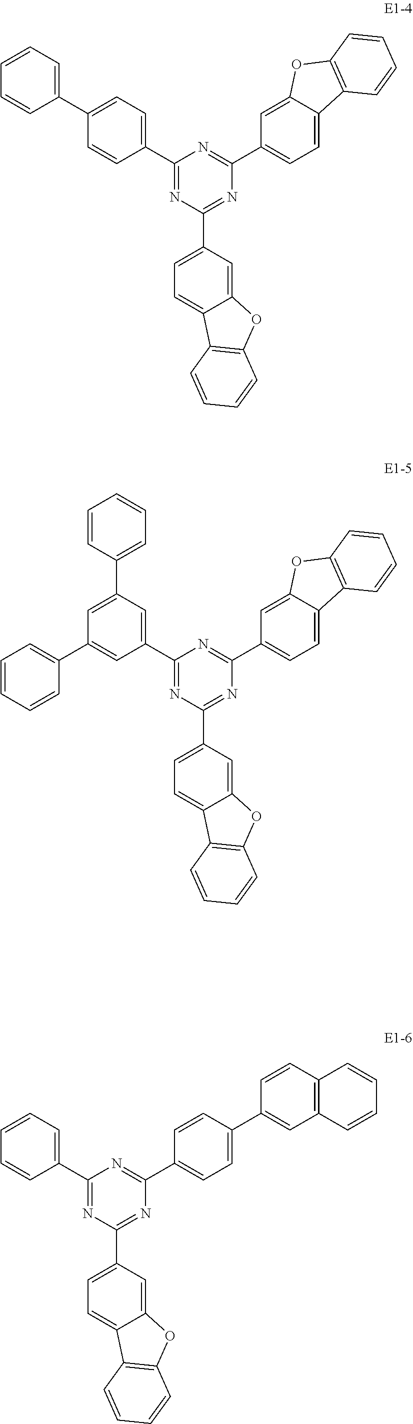 [SMILES: c1ccc(-c2ccc(-c3nc(-c4ccc5c(c4)oc4ccccc45)nc(-c4ccc5c(c4)oc4ccccc45)n3)cc2)cc1 ; c1ccc(-c2cc(-c3ccccc3)cc(-c3nc(-c4ccc5c(c4)oc4ccccc45)nc(-c4ccc5c(c4)oc4ccccc45)n3)c2)cc1 ; c1ccc(-c2nc(-c3ccc(-c4ccc5ccccc5c4)cc3)nc(-c3ccc4c(c3)oc3ccccc34)n2)cc1]

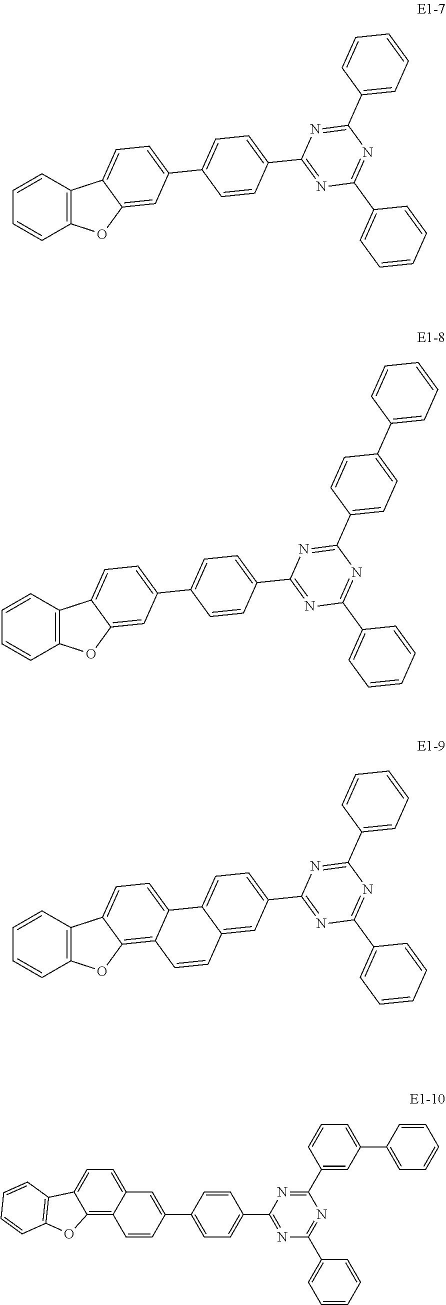 [SMILES: c1ccc(-c2nc(-c3ccccc3)nc(-c3ccc(-c4ccc5c(c4)oc4ccccc45)cc3)n2)cc1 ; c1ccc(-c2ccc(-c3nc(-c4ccccc4)nc(-c4ccc(-c5ccc6c(c5)oc5ccccc56)cc4)n3)cc2)cc1 ; c1ccc(-c2nc(-c3ccccc3)nc(-c3ccc4c(ccc5c4ccc4c6ccccc6oc45)c3)n2)cc1 ; c1ccc(-c2cccc(-c3nc(-c4ccccc4)nc(-c4ccc(-c5ccc6c(ccc7c8ccccc8oc67)c5)cc4)n3)c2)cc1]

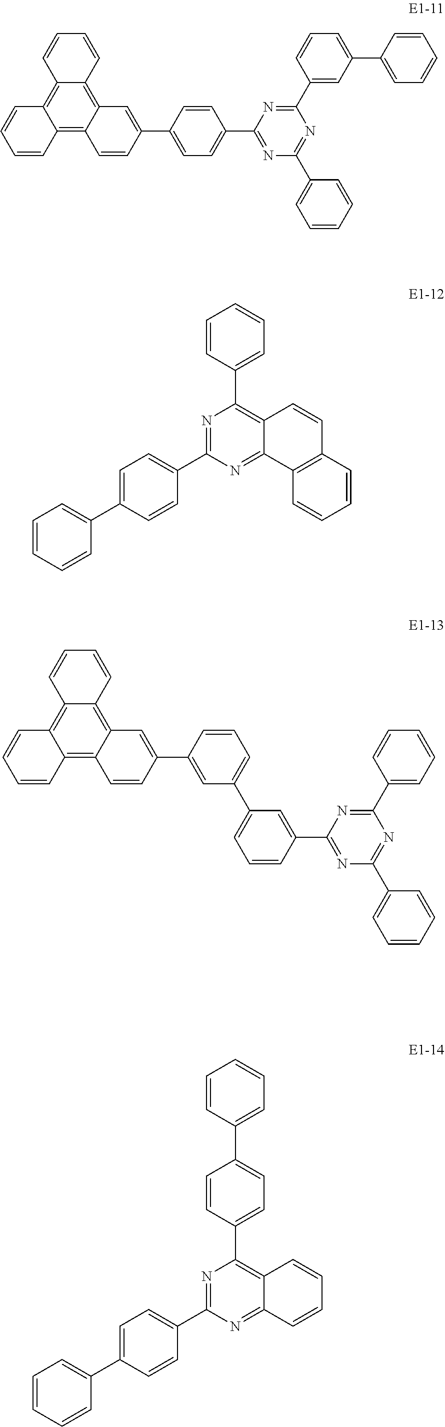 [SMILES: c1ccc(-c2cccc(-c3nc(-c4ccccc4)nc(-c4ccc(-c5ccc6c7ccccc7c7ccccc7c6c5)cc4)n3)c2)cc1 ; c1ccc(-c2ccc(-c3nc(-c4ccccc4)c4ccc5ccccc5c4n3)cc2)cc1 ; c1ccc(-c2nc(-c3ccccc3)nc(-c3cccc(-c4cccc(-c5ccc6c7ccccc7c7ccccc7c6c5)c4)c3)n2)cc1 ; c1ccc(-c2ccc(-c3nc(-c4ccc(-c5ccccc5)cc4)c4ccccc4n3)cc2)cc1]

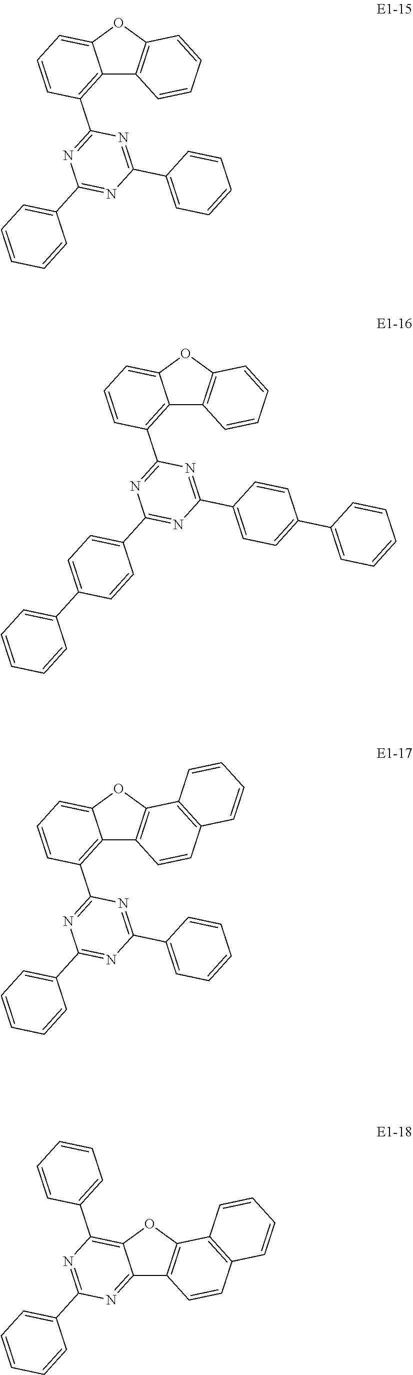 [SMILES: c1ccc(-c2nc(-c3ccccc3)nc(-c3cccc4oc5ccccc5c34)n2)cc1 ; c1ccc(-c2ccc(-c3nc(-c4ccc(-c5ccccc5)cc4)nc(-c4cccc5oc6ccccc6c45)n3)cc2)cc1 ; c1ccc(-c2nc(-c3ccccc3)nc(-c3cccc4oc5c6ccccc6ccc5c34)n2)cc1 ; c1ccc(-c2nc(-c3ccccc3)c3oc4c5ccccc5ccc4c3n2)cc1]

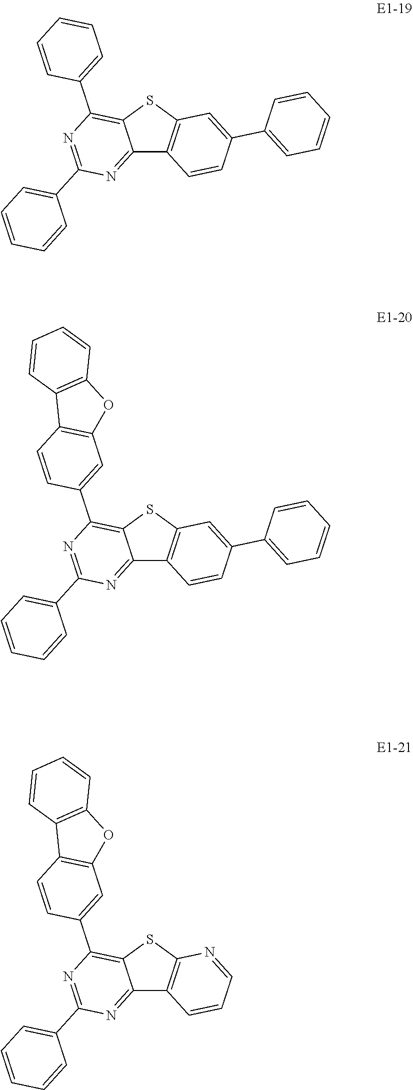 [SMILES: c1ccc(-c2ccc3c(c2)sc2c(-c4ccccc4)nc(-c4ccccc4)nc23)cc1 ; c1ccc(-c2ccc3c(c2)sc2c(-c4ccc5c(c4)oc4ccccc45)nc(-c4ccccc4)nc23)cc1 ; c1ccc(-c2nc(-c3ccc4c(c3)oc3ccccc34)c3sc4ncccc4c3n2)cc1]

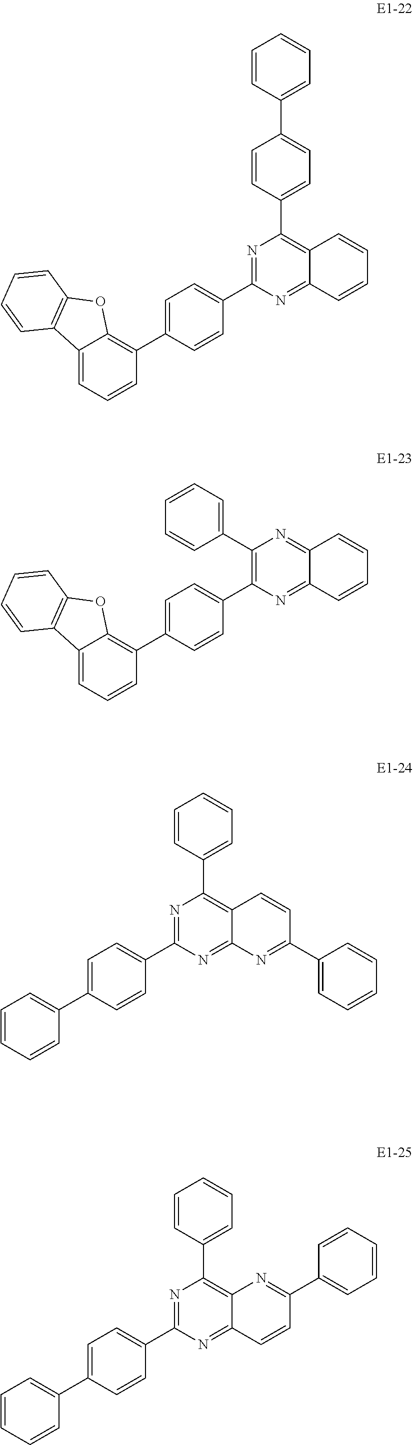 [SMILES: c1ccc(-c2ccc(-c3nc(-c4ccc(-c5cccc6c5oc5ccccc56)cc4)nc4ccccc34)cc2)cc1 ; c1ccc(-c2nc3ccccc3nc2-c2ccc(-c3cccc4c3oc3ccccc34)cc2)cc1 ; c1ccc(-c2ccc(-c3nc(-c4ccccc4)c4ccc(-c5ccccc5)nc4n3)cc2)cc1 ; c1ccc(-c2ccc(-c3nc(-c4ccccc4)c4nc(-c5ccccc5)ccc4n3)cc2)cc1]

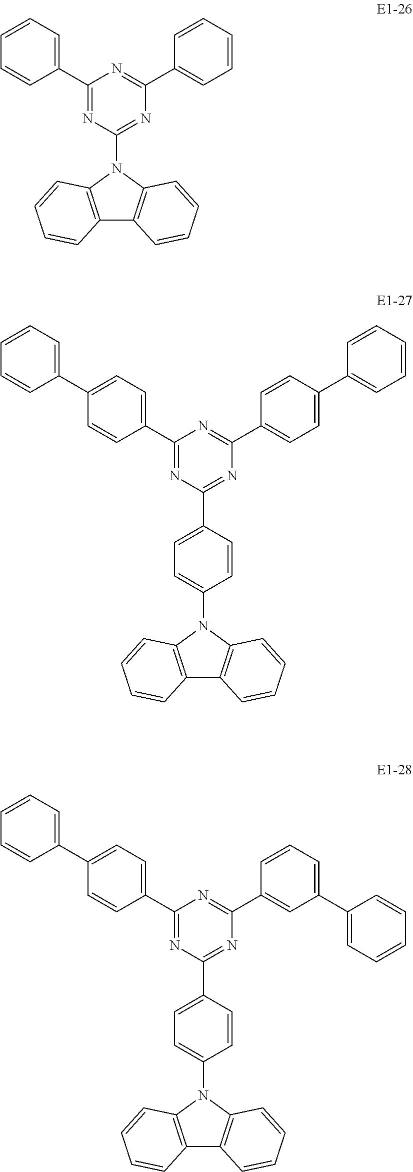 [SMILES: c1ccc(-c2nc(-c3ccccc3)nc(-n3c4ccccc4c4ccccc43)n2)cc1 ; c1ccc(-c2ccc(-c3nc(-c4ccc(-c5ccccc5)cc4)nc(-c4ccc(-n5c6ccccc6c6ccccc65)cc4)n3)cc2)cc1 ; c1ccc(-c2ccc(-c3nc(-c4ccc(-n5c6ccccc6c6ccccc65)cc4)nc(-c4cccc(-c5ccccc5)c4)n3)cc2)cc1]

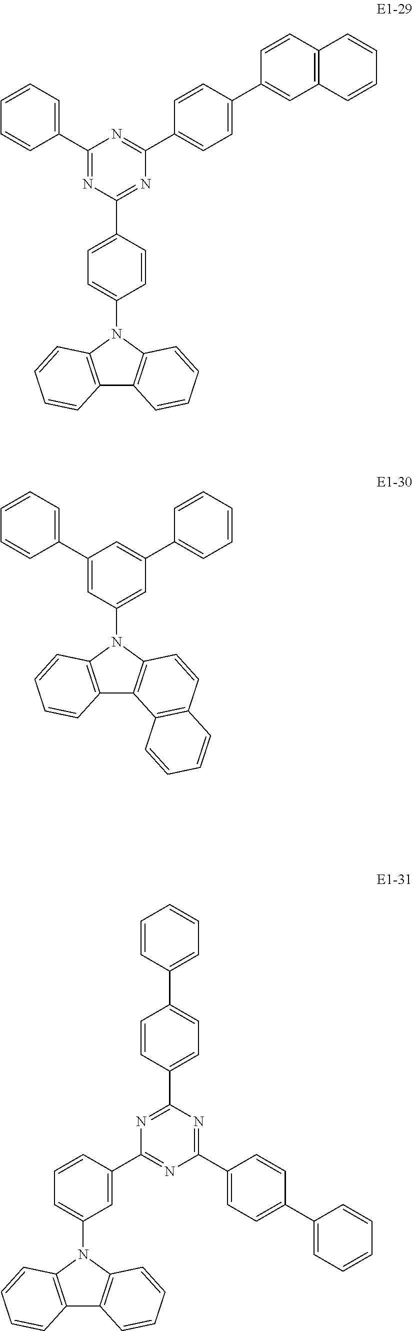 [SMILES: c1ccc(-c2nc(-c3ccc(-c4ccc5ccccc5c4)cc3)nc(-c3ccc(-n4c5ccccc5c5ccccc54)cc3)n2)cc1 ; c1ccc(-c2cc(-c3ccccc3)cc(-n3c4ccccc4c4c5ccccc5ccc43)c2)cc1 ; c1ccc(-c2ccc(-c3nc(-c4ccc(-c5ccccc5)cc4)nc(-c4cccc(-n5c6ccccc6c6ccccc65)c4)n3)cc2)cc1]

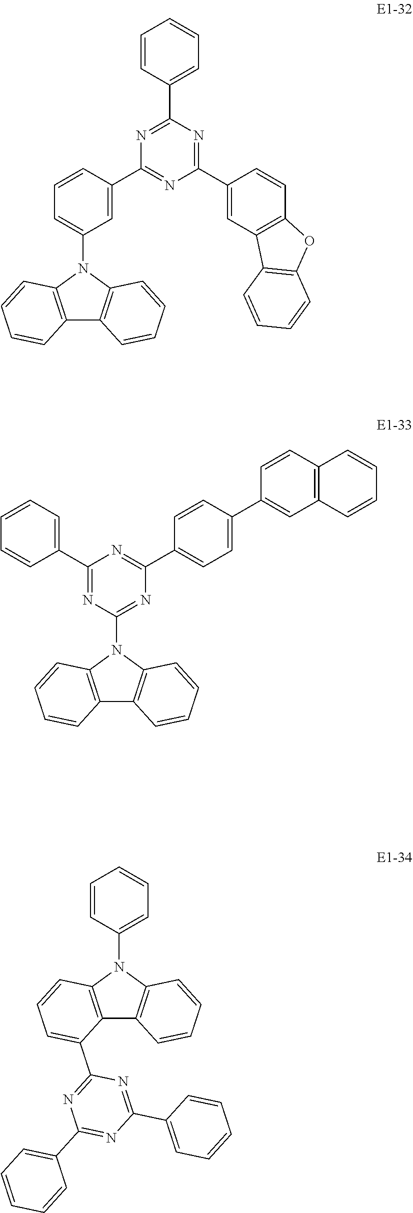 [SMILES: c1ccc(-c2nc(-c3cccc(-n4c5ccccc5c5ccccc54)c3)nc(-c3ccc4oc5ccccc5c4c3)n2)cc1 ; c1ccc(-c2nc(-c3ccc(-c4ccc5ccccc5c4)cc3)nc(-n3c4ccccc4c4ccccc43)n2)cc1 ; c1ccc(-c2nc(-c3ccccc3)nc(-c3cccc4c3c3ccccc3n4-c3ccccc3)n2)cc1]

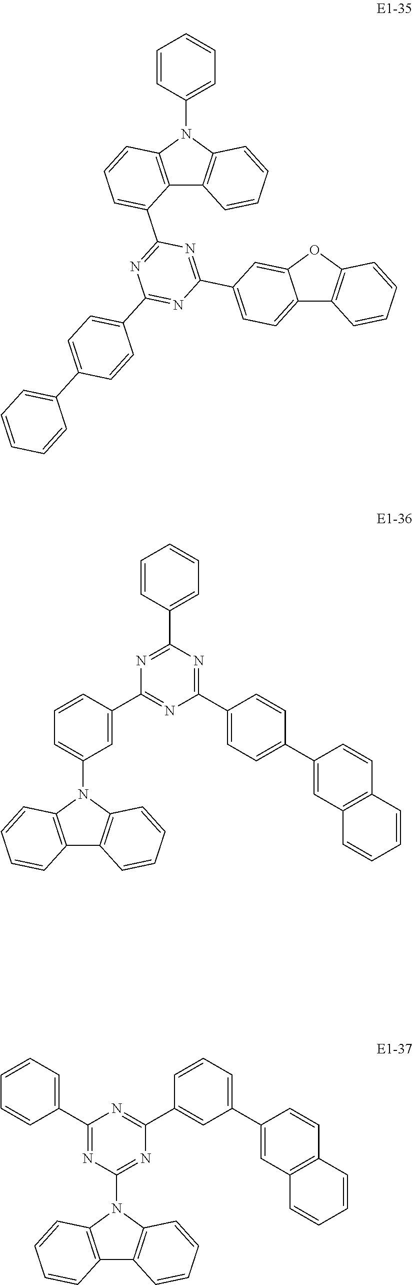 [SMILES: c1ccc(-c2ccc(-c3nc(-c4ccc5c(c4)oc4ccccc45)nc(-c4cccc5c4c4ccccc4n5-c4ccccc4)n3)cc2)cc1 ; c1ccc(-c2nc(-c3ccc(-c4ccc5ccccc5c4)cc3)nc(-c3cccc(-n4c5ccccc5c5ccccc54)c3)n2)cc1 ; c1ccc(-c2nc(-c3cccc(-c4ccc5ccccc5c4)c3)nc(-n3c4ccccc4c4ccccc43)n2)cc1]

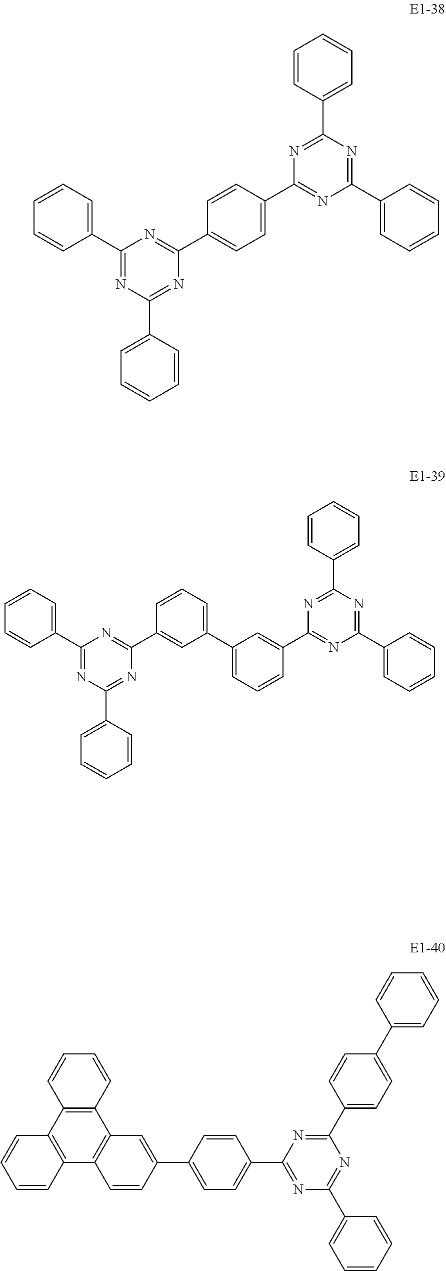 [SMILES: c1ccc(-c2nc(-c3ccccc3)nc(-c3ccc(-c4nc(-c5ccccc5)nc(-c5ccccc5)n4)cc3)n2)cc1 ; c1ccc(-c2nc(-c3ccccc3)nc(-c3cccc(-c4cccc(-c5nc(-c6ccccc6)nc(-c6ccccc6)n5)c4)c3)n2)cc1 ; c1ccc(-c2ccc(-c3nc(-c4ccccc4)nc(-c4ccc(-c5ccc6c7ccccc7c7ccccc7c6c5)cc4)n3)cc2)cc1]

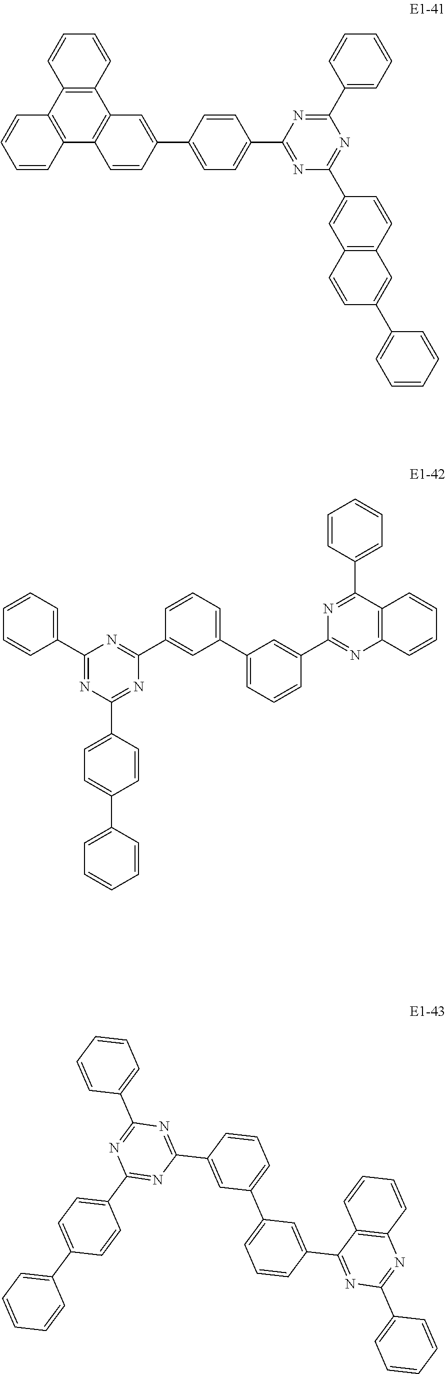 [SMILES: c1ccc(-c2ccc3cc(-c4nc(-c5ccccc5)nc(-c5ccc(-c6ccc7c8ccccc8c8ccccc8c7c6)cc5)n4)ccc3c2)cc1 ; c1ccc(-c2ccc(-c3nc(-c4ccccc4)nc(-c4cccc(-c5cccc(-c6nc(-c7ccccc7)c7ccccc7n6)c5)c4)n3)cc2)cc1 ; c1ccc(-c2ccc(-c3nc(-c4ccccc4)nc(-c4cccc(-c5cccc(-c6nc(-c7ccccc7)nc7ccccc67)c5)c4)n3)cc2)cc1]

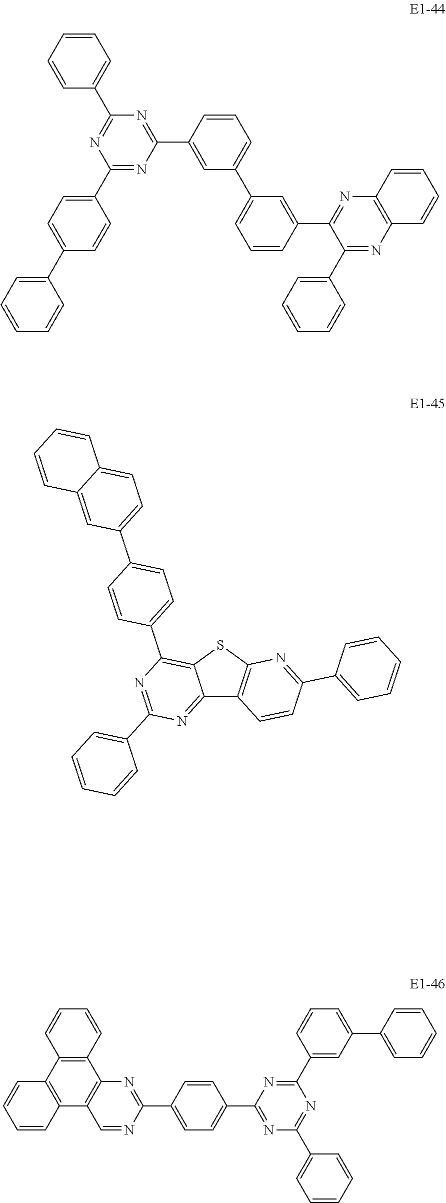 [SMILES: c1ccc(-c2ccc(-c3nc(-c4ccccc4)nc(-c4cccc(-c5cccc(-c6nc7ccccc7nc6-c6ccccc6)c5)c4)n3)cc2)cc1 ; c1ccc(-c2ccc3c(n2)sc2c(-c4ccc(-c5ccc6ccccc6c5)cc4)nc(-c4ccccc4)nc23)cc1 ; c1ccc(-c2cccc(-c3nc(-c4ccccc4)nc(-c4ccc(-c5ncc6c7ccccc7c7ccccc7c6n5)cc4)n3)c2)cc1]

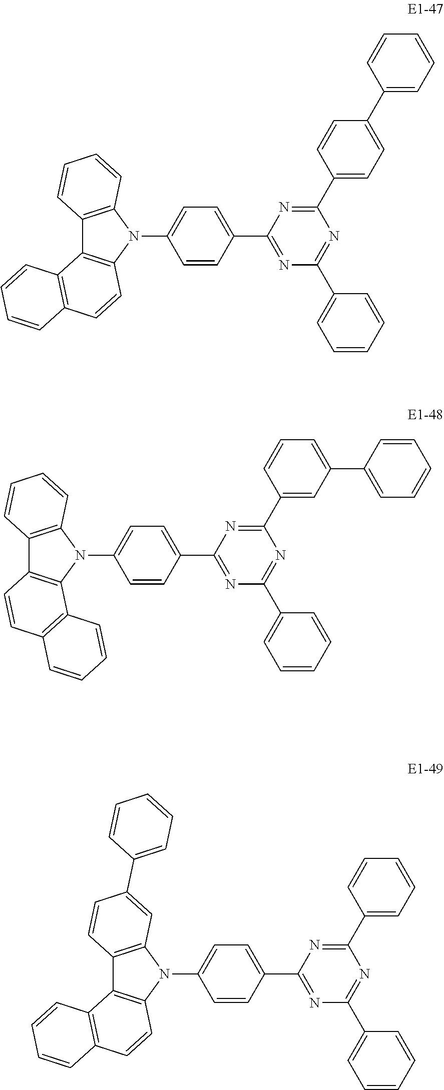 [SMILES: c1ccc(-c2ccc(-c3nc(-c4ccccc4)nc(-c4ccc(-n5c6ccccc6c6c7ccccc7ccc65)cc4)n3)cc2)cc1 ; c1ccc(-c2cccc(-c3nc(-c4ccccc4)nc(-c4ccc(-n5c6ccccc6c6ccc7ccccc7c65)cc4)n3)c2)cc1 ; c1ccc(-c2ccc3c4c5ccccc5ccc4n(-c4ccc(-c5nc(-c6ccccc6)nc(-c6ccccc6)n5)cc4)c3c2)cc1]

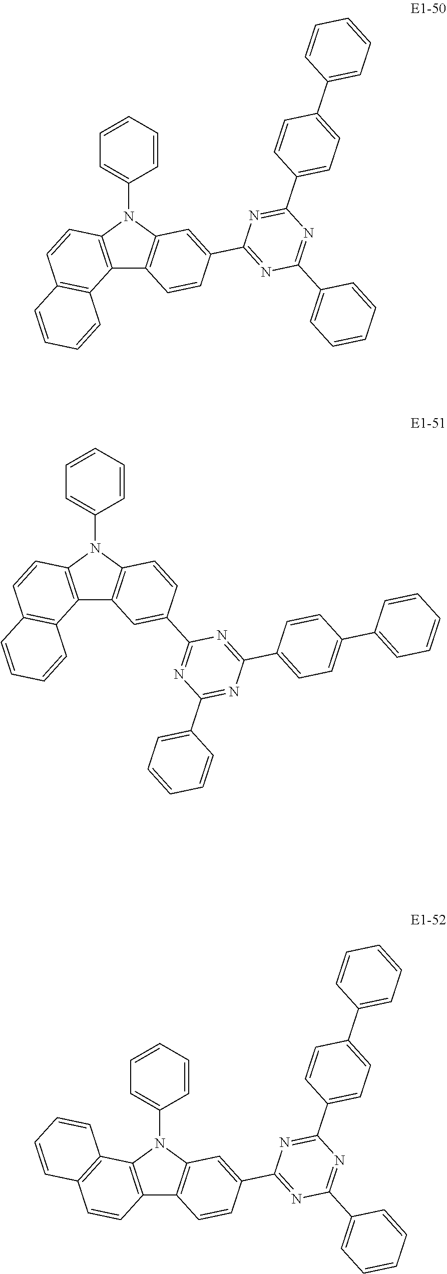 [SMILES: c1ccc(-c2ccc(-c3nc(-c4ccccc4)nc(-c4ccc5c6c7ccccc7ccc6n(-c6ccccc6)c5c4)n3)cc2)cc1 ; c1ccc(-c2ccc(-c3nc(-c4ccccc4)nc(-c4ccc5c(c4)c4c6ccccc6ccc4n5-c4ccccc4)n3)cc2)cc1 ; c1ccc(-c2ccc(-c3nc(-c4ccccc4)nc(-c4ccc5c6ccc7ccccc7c6n(-c6ccccc6)c5c4)n3)cc2)cc1]

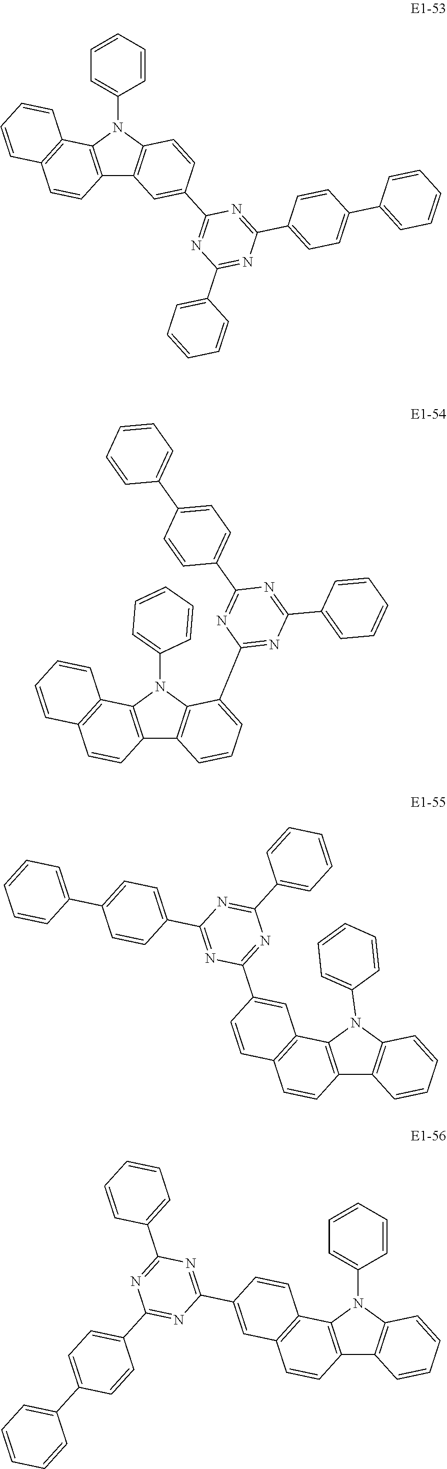 [SMILES: c1ccc(-c2ccc(-c3nc(-c4ccccc4)nc(-c4ccc5c(c4)c4ccc6ccccc6c4n5-c4ccccc4)n3)cc2)cc1 ; c1ccc(-c2ccc(-c3nc(-c4ccccc4)nc(-c4cccc5c6ccc7ccccc7c6n(-c6ccccc6)c45)n3)cc2)cc1 ; c1ccc(-c2ccc(-c3nc(-c4ccccc4)nc(-c4ccc5ccc6c7ccccc7n(-c7ccccc7)c6c5c4)n3)cc2)cc1 ; c1ccc(-c2ccc(-c3nc(-c4ccccc4)nc(-c4ccc5c(ccc6c7ccccc7n(-c7ccccc7)c56)c4)n3)cc2)cc1]

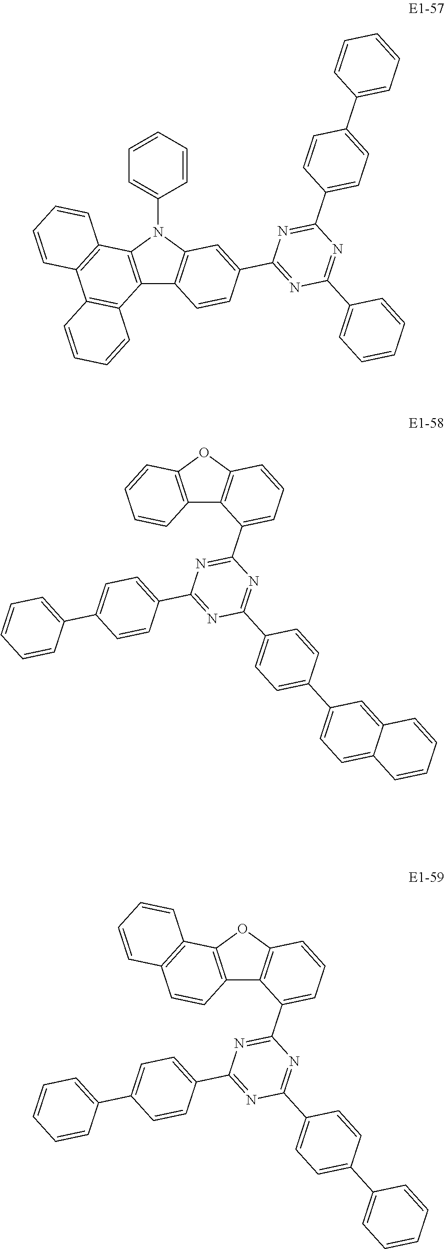 [SMILES: c1ccc(-c2ccc(-c3nc(-c4ccccc4)nc(-c4ccc5c6c7ccccc7c7ccccc7c6n(-c6ccccc6)c5c4)n3)cc2)cc1 ; c1ccc(-c2ccc(-c3nc(-c4ccc(-c5ccc6ccccc6c5)cc4)nc(-c4cccc5oc6ccccc6c45)n3)cc2)cc1 ; c1ccc(-c2ccc(-c3nc(-c4ccc(-c5ccccc5)cc4)nc(-c4cccc5oc6c7ccccc7ccc6c45)n3)cc2)cc1]

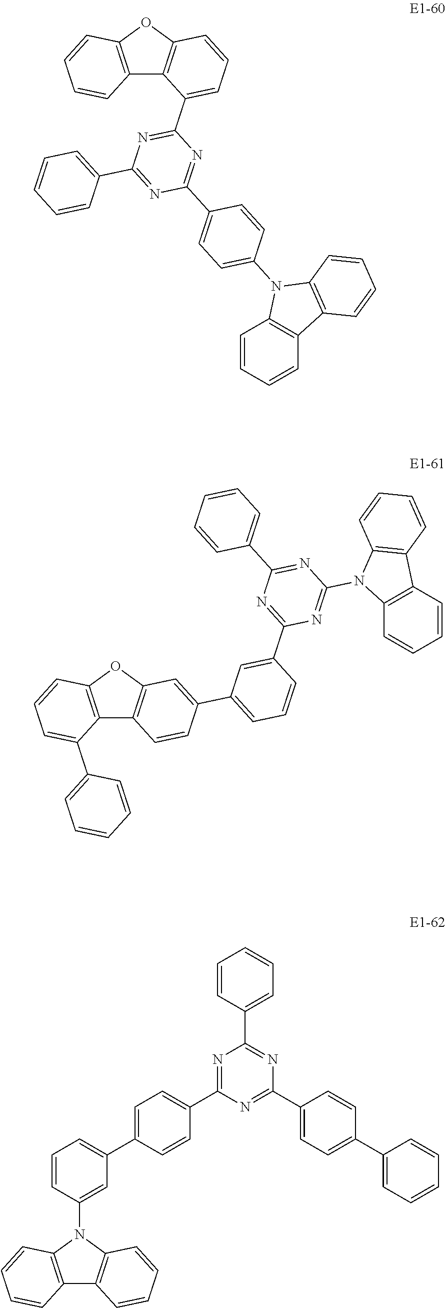 [SMILES: c1ccc(-c2nc(-c3ccc(-n4c5ccccc5c5ccccc54)cc3)nc(-c3cccc4oc5ccccc5c34)n2)cc1 ; c1ccc(-c2nc(-c3cccc(-c4ccc5c(c4)oc4cccc(-c6ccccc6)c45)c3)nc(-n3c4ccccc4c4ccccc43)n2)cc1 ; c1ccc(-c2ccc(-c3nc(-c4ccccc4)nc(-c4ccc(-c5cccc(-n6c7ccccc7c7ccccc76)c5)cc4)n3)cc2)cc1]

In one or more embodiments, the bipolar compound may be at least one of Compounds BP1-1 to BP1-17:

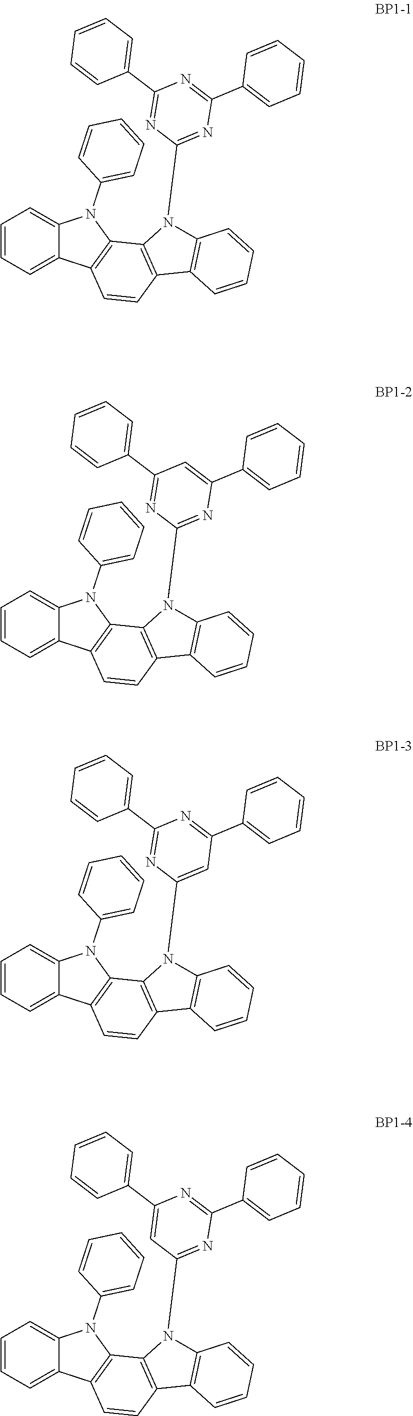 [SMILES: c1ccc(-c2nc(-c3ccccc3)nc(-n3c4ccccc4c4ccc5c6ccccc6n(-c6ccccc6)c5c43)n2)cc1 ; c1ccc(-c2cc(-c3ccccc3)nc(-n3c4ccccc4c4ccc5c6ccccc6n(-c6ccccc6)c5c43)n2)cc1 ; c1ccc(-c2cc(-n3c4ccccc4c4ccc5c6ccccc6n(-c6ccccc6)c5c43)nc(-c3ccccc3)n2)cc1 ; c1ccc(-c2cc(-n3c4ccccc4c4ccc5c6ccccc6n(-c6ccccc6)c5c43)nc(-c3ccccc3)n2)cc1]

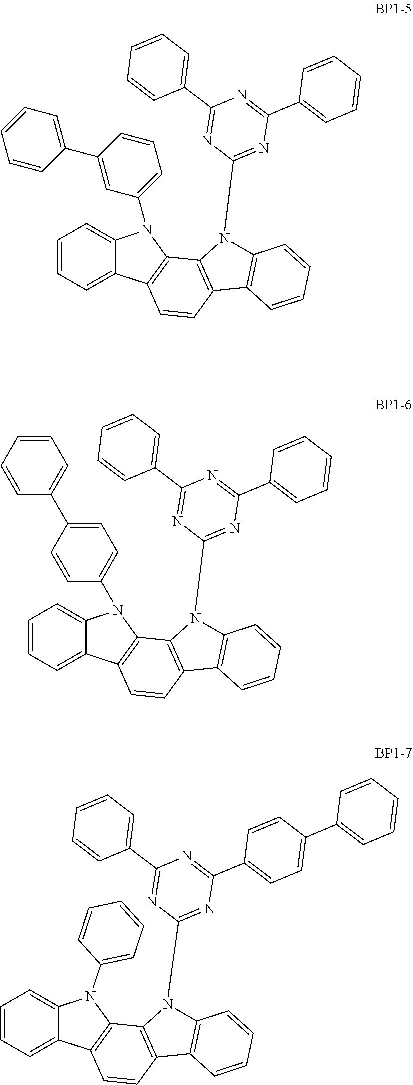 [SMILES: c1ccc(-c2cccc(-n3c4ccccc4c4ccc5c6ccccc6n(-c6nc(-c7ccccc7)nc(-c7ccccc7)n6)c5c43)c2)cc1 ; c1ccc(-c2ccc(-n3c4ccccc4c4ccc5c6ccccc6n(-c6nc(-c7ccccc7)nc(-c7ccccc7)n6)c5c43)cc2)cc1 ; c1ccc(-c2ccc(-c3nc(-c4ccccc4)nc(-n4c5ccccc5c5ccc6c7ccccc7n(-c7ccccc7)c6c54)n3)cc2)cc1]

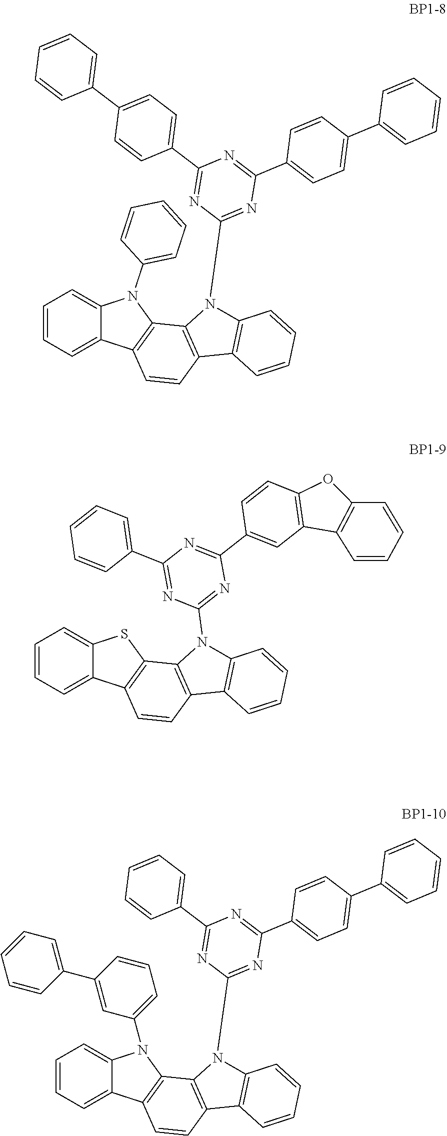 [SMILES: c1ccc(-c2ccc(-c3nc(-c4ccc(-c5ccccc5)cc4)nc(-n4c5ccccc5c5ccc6c7ccccc7n(-c7ccccc7)c6c54)n3)cc2)cc1 ; c1ccc(-c2nc(-c3ccc4oc5ccccc5c4c3)nc(-n3c4ccccc4c4ccc5c6ccccc6sc5c43)n2)cc1 ; c1ccc(-c2ccc(-c3nc(-c4ccccc4)nc(-n4c5ccccc5c5ccc6c7ccccc7n(-c7cccc(-c8ccccc8)c7)c6c54)n3)cc2)cc1]

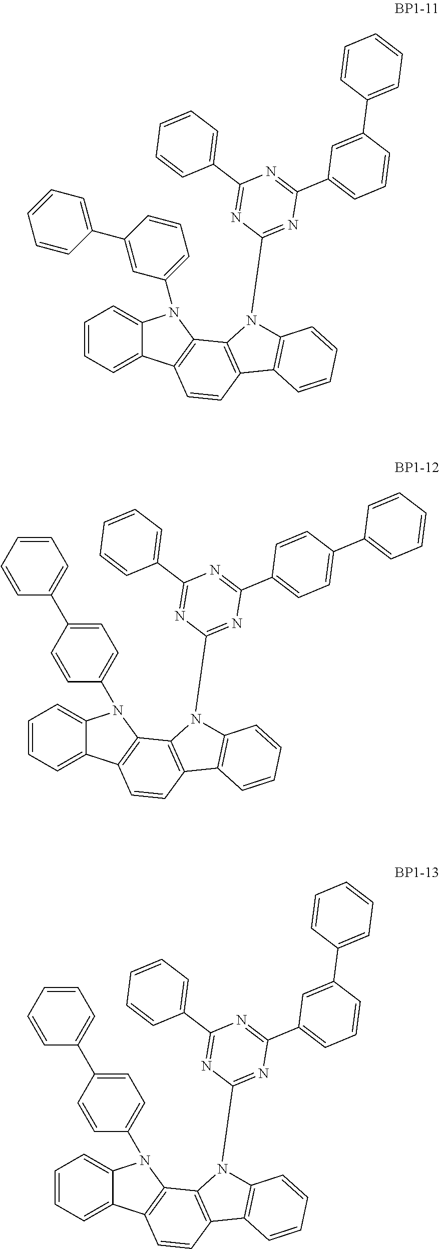 [SMILES: c1ccc(-c2cccc(-c3nc(-c4ccccc4)nc(-n4c5ccccc5c5ccc6c7ccccc7n(-c7cccc(-c8ccccc8)c7)c6c54)n3)c2)cc1 ; c1ccc(-c2ccc(-c3nc(-c4ccccc4)nc(-n4c5ccccc5c5ccc6c7ccccc7n(-c7ccc(-c8ccccc8)cc7)c6c54)n3)cc2)cc1 ; c1ccc(-c2ccc(-n3c4ccccc4c4ccc5c6ccccc6n(-c6nc(-c7ccccc7)nc(-c7cccc(-c8ccccc8)c7)n6)c5c43)cc2)cc1]

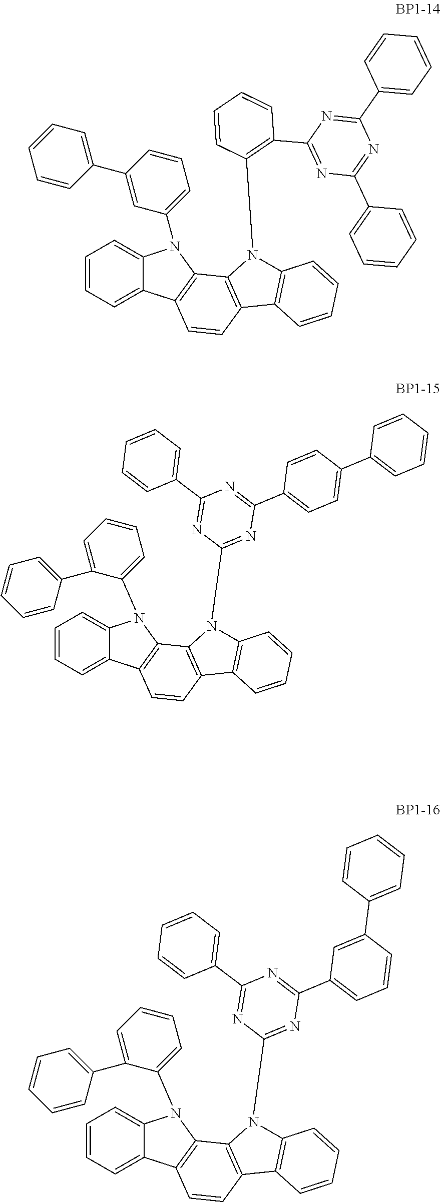 [SMILES: c1ccc(-c2cccc(-n3c4ccccc4c4ccc5c6ccccc6n(-c6ccccc6-c6nc(-c7ccccc7)nc(-c7ccccc7)n6)c5c43)c2)cc1 ; c1ccc(-c2ccc(-c3nc(-c4ccccc4)nc(-n4c5ccccc5c5ccc6c7ccccc7n(-c7ccccc7-c7ccccc7)c6c54)n3)cc2)cc1 ; c1ccc(-c2cccc(-c3nc(-c4ccccc4)nc(-n4c5ccccc5c5ccc6c7ccccc7n(-c7ccccc7-c7ccccc7)c6c54)n3)c2)cc1]

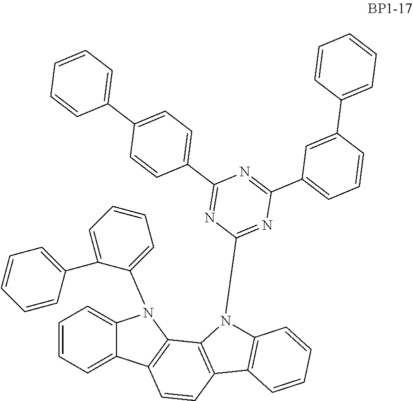 [SMILES: c1ccc(-c2ccc(-c3nc(-c4cccc(-c5ccccc5)c4)nc(-n4c5ccccc5c5ccc6c7ccccc7n(-c7ccccc7-c7ccccc7)c6c54)n3)cc2)cc1]

Meanwhile, the mixed layer 15 may not include compounds of Group A:

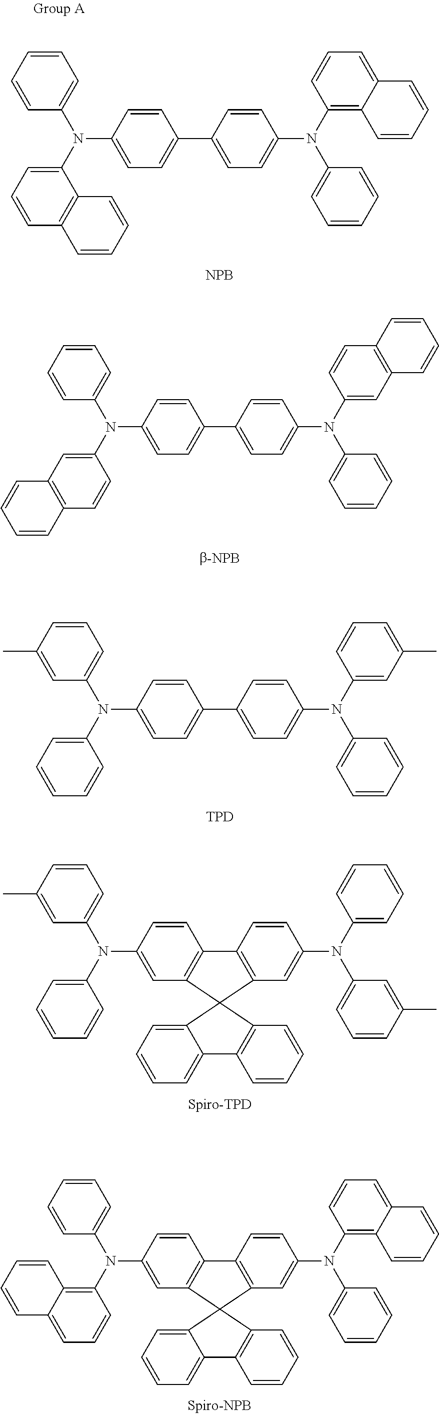

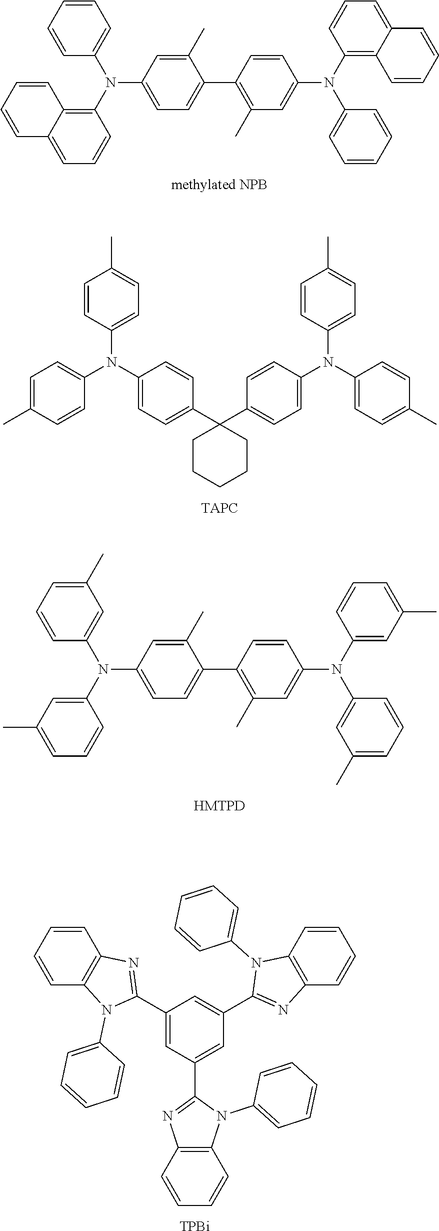

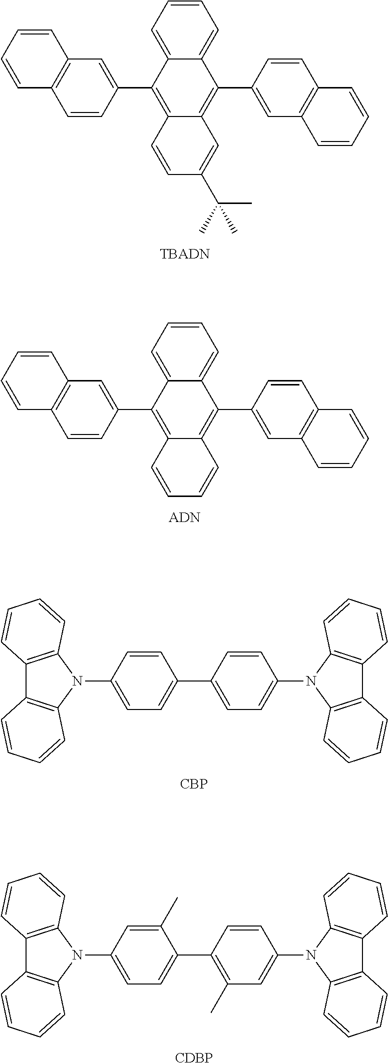

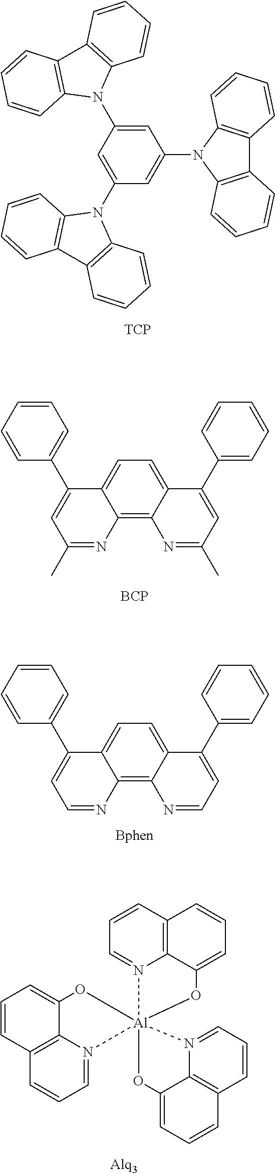

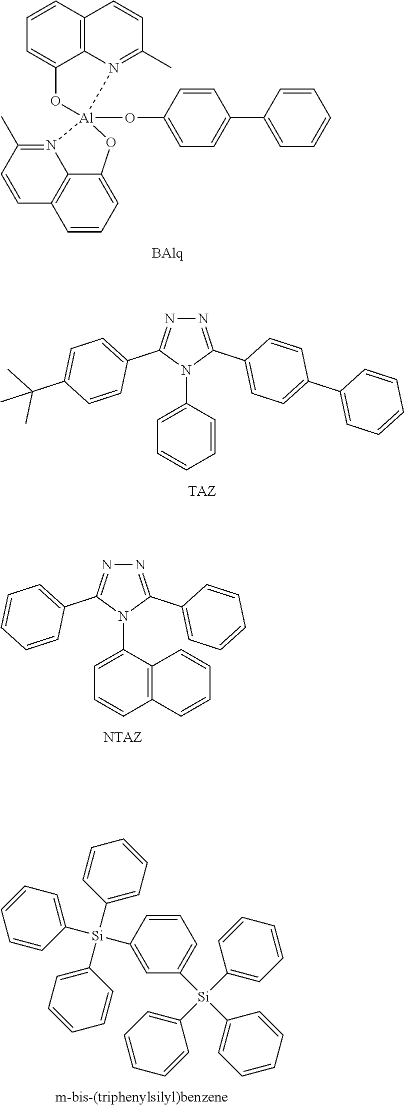

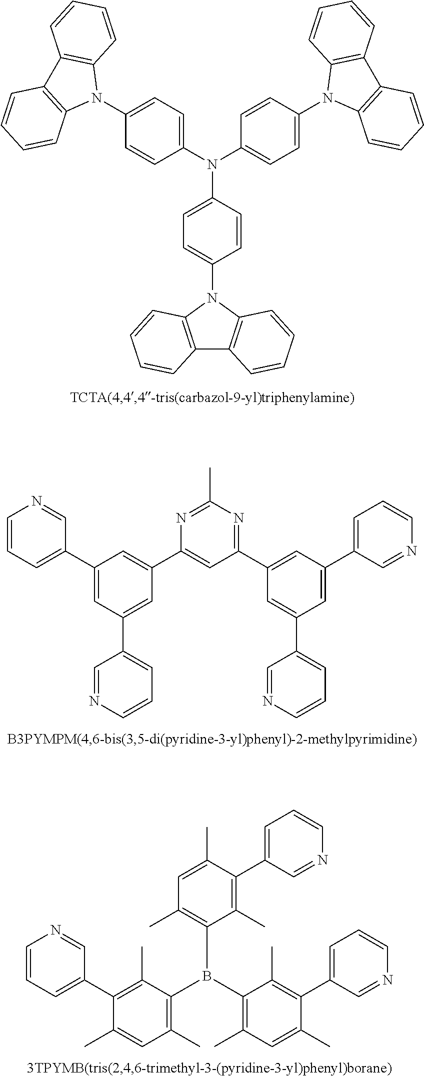 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1 ; Cc1nc(-c2cc(-c3cccnc3)cc(-c3cccnc3)c2)cc(-c2cc(-c3cccnc3)cc(-c3cccnc3)c2)n1 ; Cc1cc(C)c(-c2cccnc2)c(C)c1B(c1c(C)cc(C)c(-c2cccnc2)c1C)c1c(C)cc(C)c(-c2cccnc2)c1C]

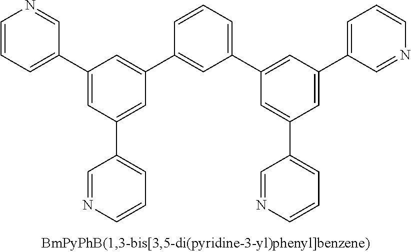 [SMILES: c1cncc(-c2cc(-c3cccnc3)cc(-c3cccc(-c4cc(-c5cccnc5)cc(-c5cccnc5)c4)c3)c2)c1]

### Description of FIG. 11

FIG. 11 is a diagram schematically illustrating one or more embodiments of a light-emitting device 101 including the mixed layer 15. The light-emitting device 101 in FIG. 11 includes a first electrode 110, a second electrode 190 facing the first electrode 110, and an interlayer (not shown) arranged between the first electrode 110 and the second electrode 190, wherein the interlayer includes an emission layer 150 arranged between the first electrode 110 and the second electrode 190, a hole transport region 120 arranged between the first electrode 110 and the emission layer 150, and an electron transport region 170 arranged between the emission layer 150 and the second electrode 190. The emission layer 150 may be the mixed layer 15 as described herein.

A substrate may be additionally arranged under the first electrode 110 or above the second electrode 190. For use as the substrate, any substrate that is used in light-emitting devices of the related art may be used, and the substrate may be a glass substrate or a transparent plastic substrate, each having excellent mechanical strength, thermal stability, transparency, surface smoothness, ease of handling, and water resistance.

The first electrode 110 may be formed by providing, on the substrate, a material for forming the first electrode 110, by using a deposition or sputtering method. The first electrode 110 may be an anode. The material for forming the first electrode 110 may include materials with a high work function to facilitate hole injection. The first electrode 110 may be a reflective electrode. The material for forming the first electrode 110 may be indium tin oxide (ITO), indium zinc oxide (IZO), tin oxide (SnO₂), or zinc oxide (ZnO). In one or more embodiments, the material for forming the first electrode 110 may be metal, such as magnesium (Mg), aluminum (Al), silver (Ag), aluminum-lithium (Al—Li), calcium (Ca), magnesium-indium (Mg—In), or magnesium-silver (Mg—Ag).

The first electrode 110 may have a single-layered structure or a multi-layered structure including two or more layers. For example, the first electrode 110 may have a three-layered structure of ITO/Ag/ITO.

The hole transport region 120 may be arranged between the first electrode 110 and the emission layer 150.

The hole transport region 120 may include a hole injection layer, a hole transport layer, an electron blocking layer, a buffer layer, or a combination thereof.

The hole transport region 120 may include only a hole injection layer or only a hole transport layer. In one or more embodiments, the hole transport region 120 may have a hole injection layer/hole transport layer structure or a hole injection layer/hole transport layer/electron blocking layer structure, which are sequentially stacked in this stated order from the first electrode 110.

When the hole transport region 120 includes a hole injection layer, the hole injection layer may be formed on the first electrode 110 by using one or more suitable methods, for example, a vacuum deposition method, a spin coating method, a casting method, a Langmuir-Blodgett (LB) method, and/or an ink-jet printing method.

When a hole injection layer is formed by vacuum deposition, the deposition conditions may vary depending on a material that is used to form the hole injection layer, and the structure and thermal characteristics of the hole injection layer. For example, the deposition conditions may include a deposition temperature of about 100° C. to about 500° C., a vacuum pressure of about 10⁻⁸ torr to about 10⁻³ torr, and a deposition rate of about 0.01 angstroms per second (Å/sec) to about 100 Å/sec.

When the hole injection layer is formed by spin coating, the coating conditions may vary depending on a material for forming the hole injection layer, and the structure and thermal characteristics of the hole injection layer. For example, the coating conditions may include a coating speed in a range of about 2,000 revolutions per minute (rpm) to about 5,000 rpm and a heat treatment temperature in a range of about 80° C. to about 200° C. for removing a solvent after coating.

The conditions for forming the hole transport layer and the electron blocking layer may be as the conditions for forming the hole injection layer.

The hole transport region 120 may include, for example, 4,4′,4″-tris(3-methylphenylphenylamino)triphenylamine (m-MTDATA), 4,4′,4″-tris(N,N-diphenylamino)triphenylamine (TDATA), 4,4′,4″-tris{N-(2-naphthyl)-N-phenylamino}-triphenylamine (2-TNATA), N,N′-di(1-naphthyl)-N,N′-diphenylbenzidine (NPB), p-NPB, N,N′-bis(3-methylphenyl)-N,N′-diphenyl-[1,1-biphenyl]-4,4′-diamine (TPD), spiro-TPD, spiro-NPB, methylated NPB, 4,4′-cyclohexylidene bis[N,N-bis(4-methylphenyl)benzenamine] (TAPC), 4,4′-bis[N,N′-(3-tolyl)amino]-3,3′-dimethylbiphenyl (HMTPD), 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), a compound represented by Formula 201, a compound represented by Formula 202, or a combination thereof:

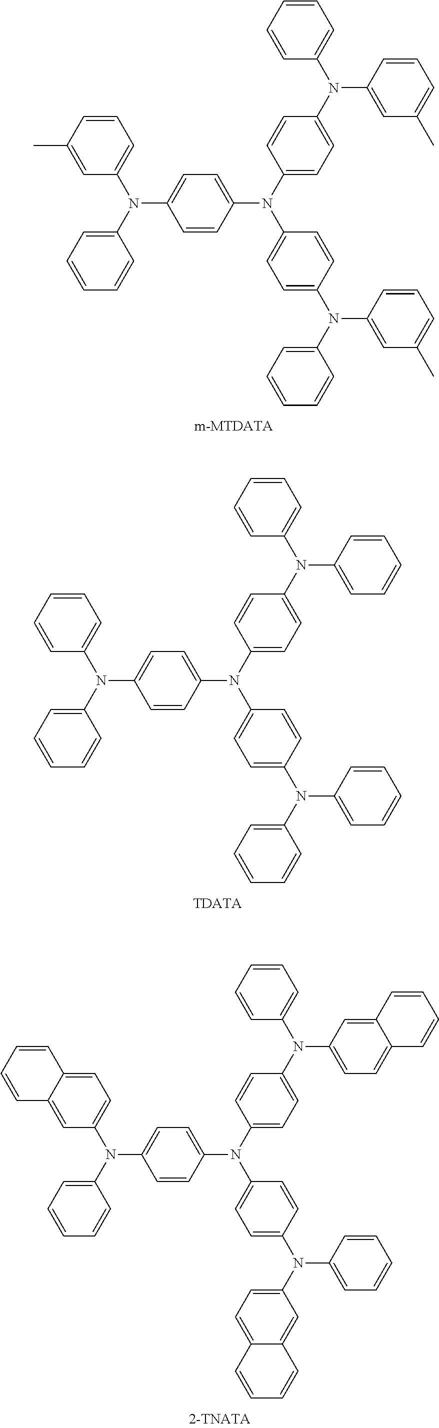

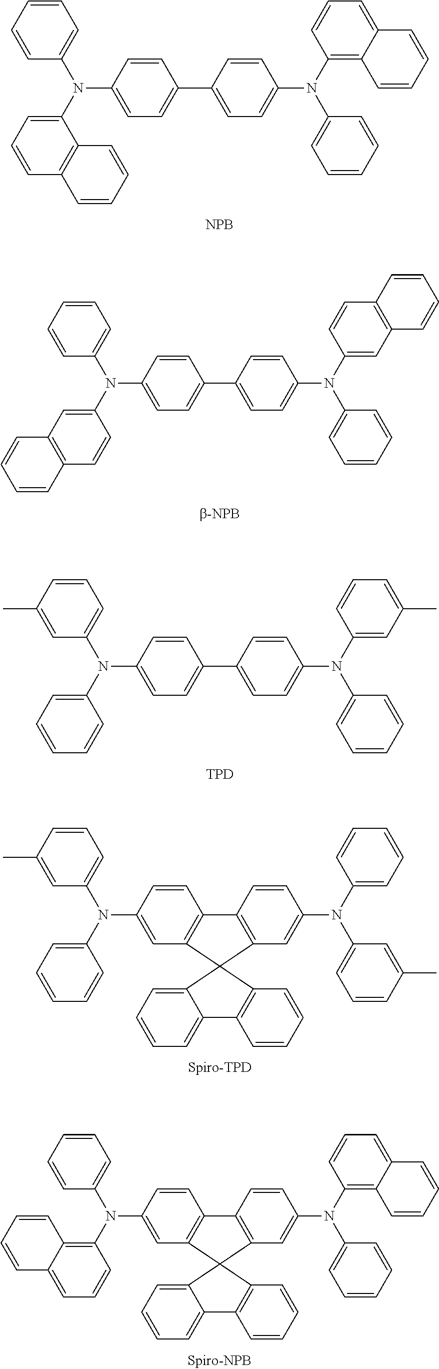

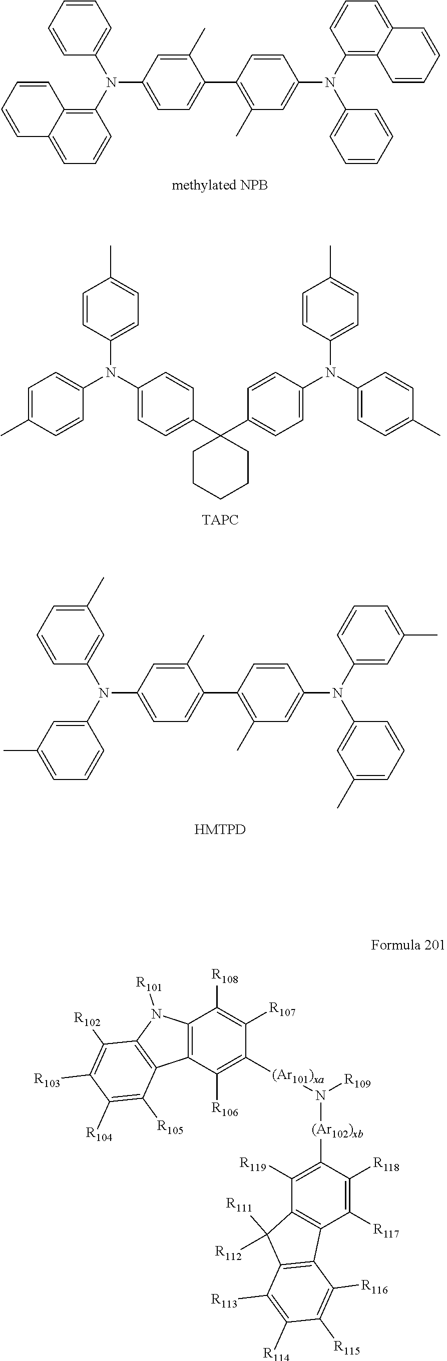

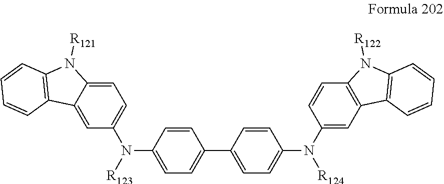

Ar₁₀₁ and Ar₁₀₂ in Formula 201 may each independently be a phenylene group, a pentalenylene group, an indenylene group, a naphthylene group, an azulenylene group, a heptalenylene group, an acenaphthylene group, a fluorenylene group, a phenalenylene group, a phenanthrenylene group, an anthracenylene group, a fluoranthenylene group, a triphenylenylene group, a pyrenylene group, a chrysenylenylene group, a naphthacenylene group, a picenylene group, a perylenylene group, or a pentacenylene group, each unsubstituted or substituted with deuterium, —F, —Cl, —Br, —I, —SF₅, a hydroxyl group, a cyano group, a nitro group, an amino group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₃-C₁₀ cycloalkenyl group, a C₁-C₁₀ heterocycloalkyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, a monovalent non-aromatic condensed heteropolycyclic group, or a combination thereof.

xa and xb in Formula 201 may each independently be an integer from 0 to 5, or may each independently be 0, 1, or 2. For example, xa may be 1 and xb may be 0.

R₁₀₁ to R₁₀₈, R₁₁₁ to R₁₁₉, and R₁₂₁ to R₁₂₄ in Formulae 201 and 202 may each independently be:
hydrogen, deuterium, —F, —Cl, —Br, —I, —SF₅, a hydroxyl group, a cyano group, a nitro group, an amino group, a C₁-C₁₀ alkyl group (for example, a methyl group, an ethyl group, a propyl group, a butyl group, a pentyl group, a hexyl group, or the like), a C₁-C₁₀ alkoxy group (for example, a methoxy group, an ethoxy group, a propoxy group, a butoxy group, a pentoxy group, or the like), or a C₁-C₁₀ alkylthio group;
a C₁-C₁₀ alkyl group, a C₁-C₁₀ alkoxy group, or a C₁-C₁₀ alkylthio group, each unsubstituted or substituted with at least one of deuterium, —F, —Cl, —Br, —I, —SF₅, a hydroxyl group, a cyano group, a nitro group, an amino group, or a combination thereof; or
a phenyl group, a naphthyl group, an anthracenyl group, a fluorenyl group, or a pyrenyl group, each unsubstituted or substituted with at least one of deuterium, —F, —Cl, —Br, —I, —SF₅, a hydroxyl group, a cyano group, a nitro group, an amino group, a C₁-C₁₀ alkyl group, a C₁-C₁₀ alkoxy group, a C₁-C₁₀ alkylthio group, or a combination thereof.

R₁₀₉ in Formula 201 may be a phenyl group, a naphthyl group, an anthracenyl group, or a pyridinyl group, each unsubstituted or substituted with deuterium, —F, —Cl, —Br, —I, —SF₅, a hydroxyl group, a cyano group, a nitro group, an amino group, a C₁-C₂₀ alkyl group, a C₁-C₂₀ alkoxy group, a C₁-C₂₀ alkylthio group, a phenyl group, a naphthyl group, an anthracenyl group, a pyridinyl group, or a combination thereof.

In one or more embodiments, the compound represented by Formula 201 may be represented by Formula 201A:

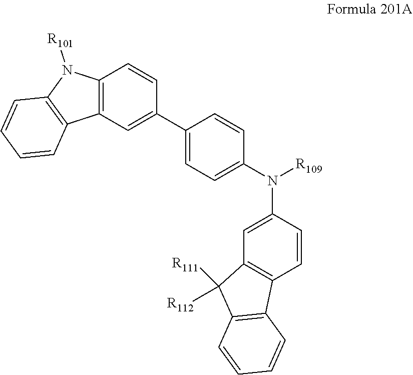

wherein, in Formula 201A, R₁₀₁, R₁₁₁, R₁₁₂, and R₁₀₉ are respectively as those described herein.

For example, the hole transport region 120 may include one of Compounds HT1 to HT20 or a combination thereof:

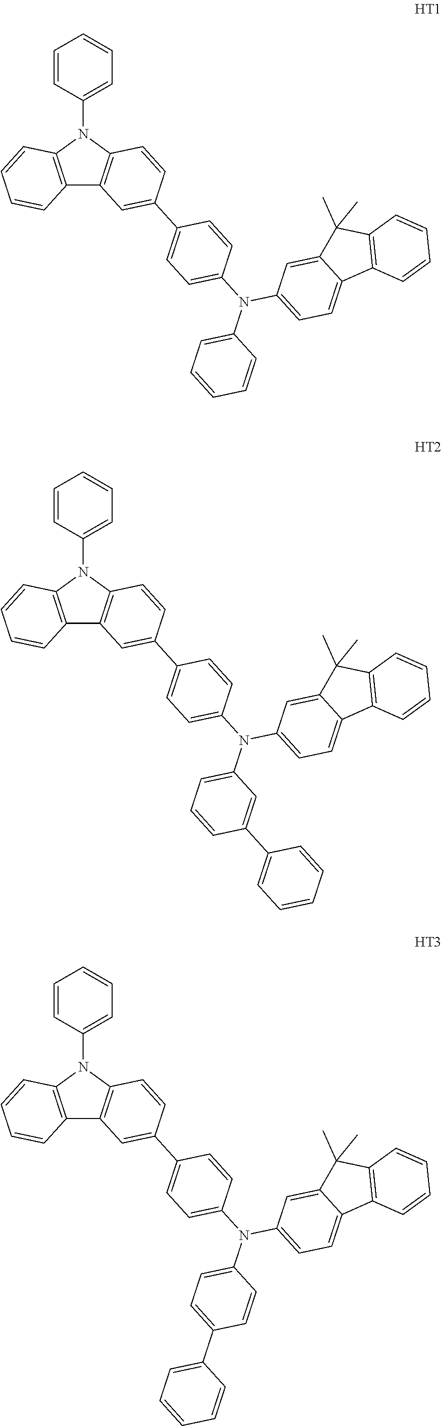 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

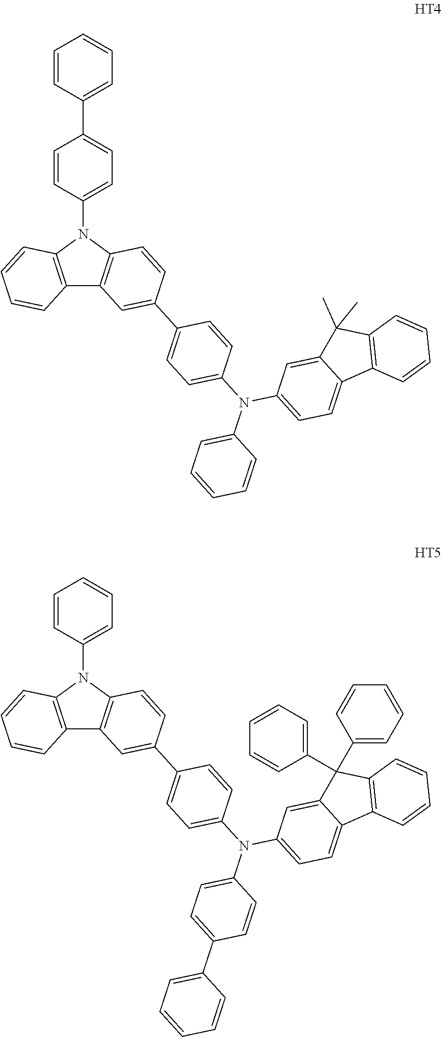 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

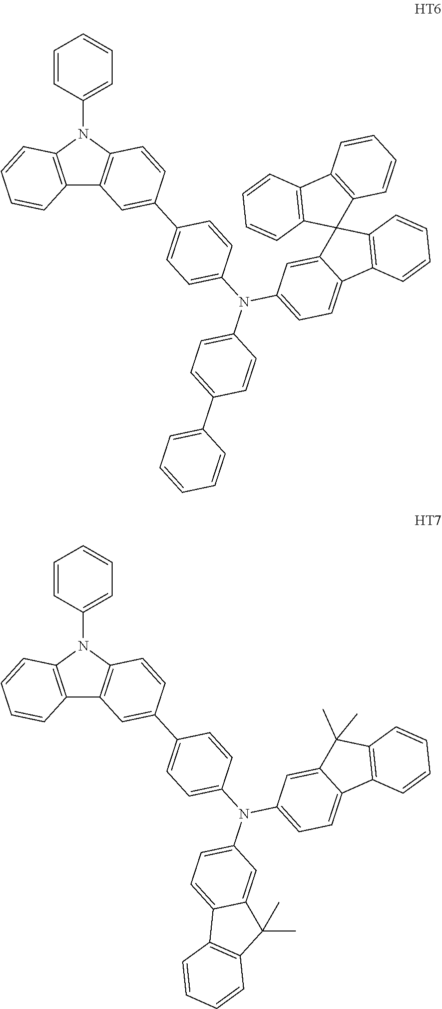 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21]

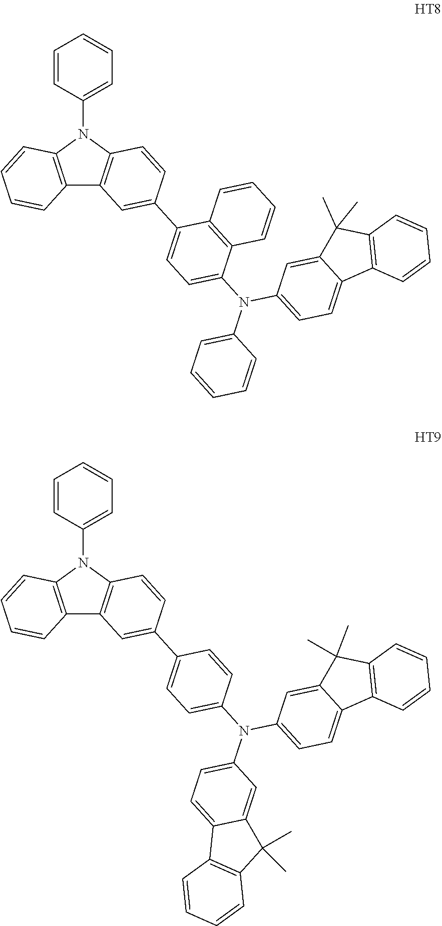 [SMILES: CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21]

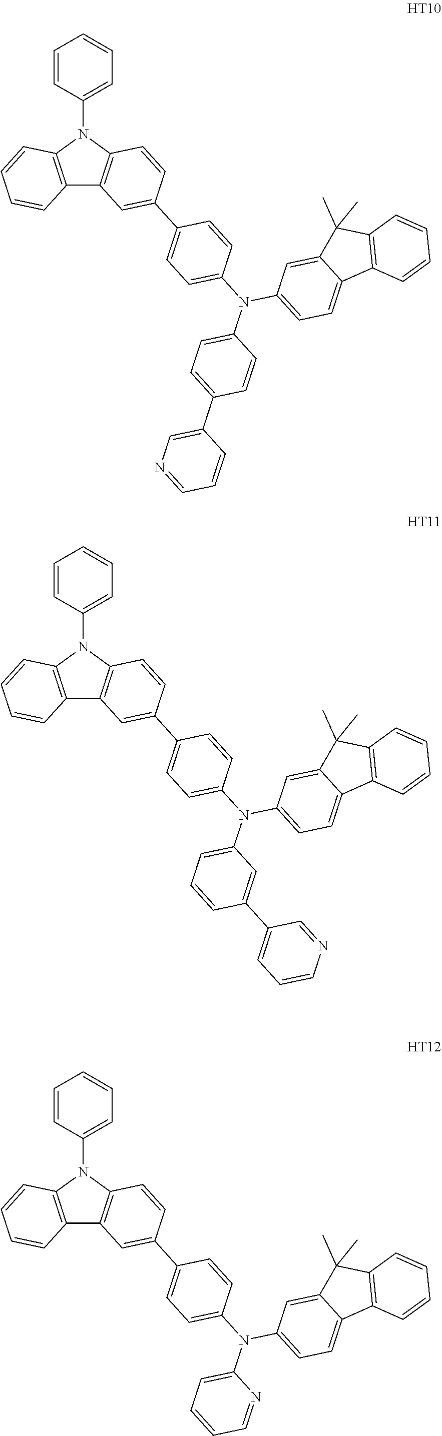 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21]

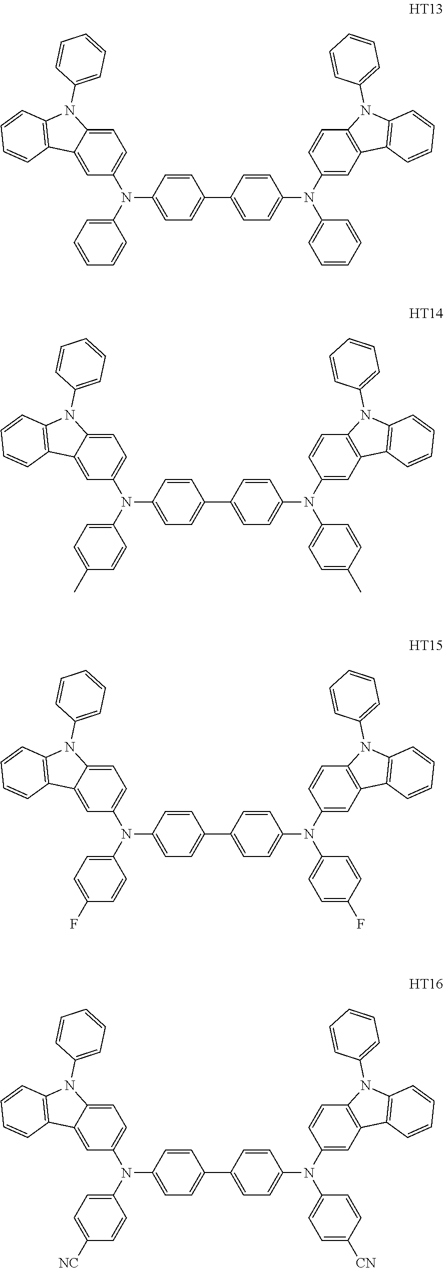 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1]

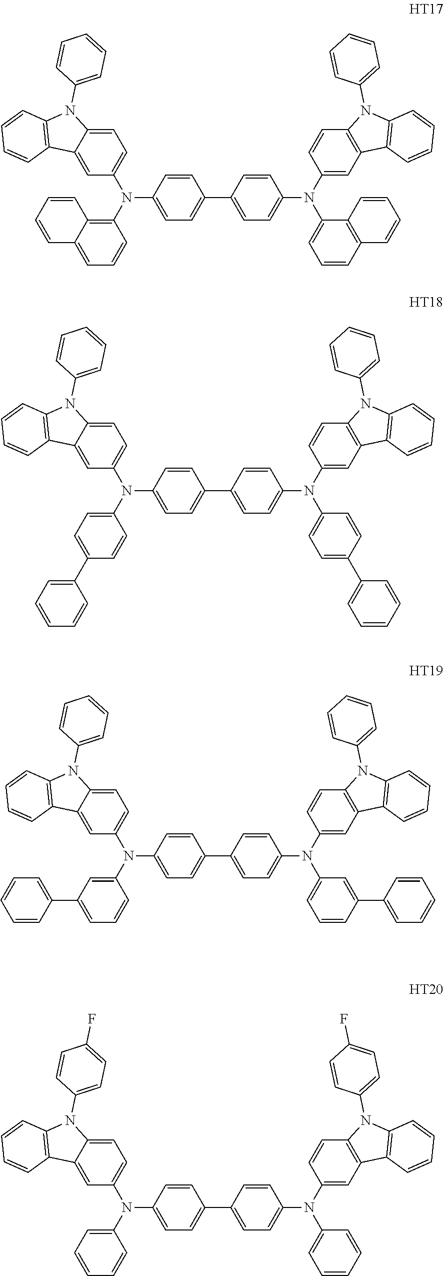 [SMILES: c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

A thickness of the hole transport region 120 may be in a range of about 100 angstroms (Å) to about 10,000 Å, for example, about 100 Å to about 1,000 Å. When the hole transport region 120 includes a hole injection layer, a hole transport layer, an electron blocking layer, or a combination thereof, a thickness of the hole injection layer may be in a range of about 100 Å to about 10,000 Å, for example, about 100 Å to about 1,000 Å, and a thickness of the hole transport layer may be in a range of about 50 Å to about 2,000 Å, for example, about 100 Å to about 1,500 Å. When the thicknesses of the hole transport region 120, the hole injection layer, and the hole transport layer are within these ranges, satisfactory hole transporting characteristics may be obtained without a substantial increase in driving voltage.

In addition to the above-described materials, the hole transport region 120 may further include a charge-generation material to improve conductivity. The charge-generation material may be homogeneously or non-homogeneously dispersed in the hole transport region 120.

The charge-generation material may be, for example, a p-dopant. The p-dopant may be a quinone derivative, a metal oxide, a cyano group-containing compound, or a combination thereof. For example, the p-dopant may be a quinone derivative such as tetracyanoquinodimethane (TCNQ), 2,3,5,6-tetrafluoro-tetracyano-1,4-benzoquinonedimethane (F4-TCNQ), or F6-TCNNQ; metal oxide, such as tungsten oxide or molybdenum oxide; a cyano group-containing compound, such as Compound HT-D1; or a combination thereof:

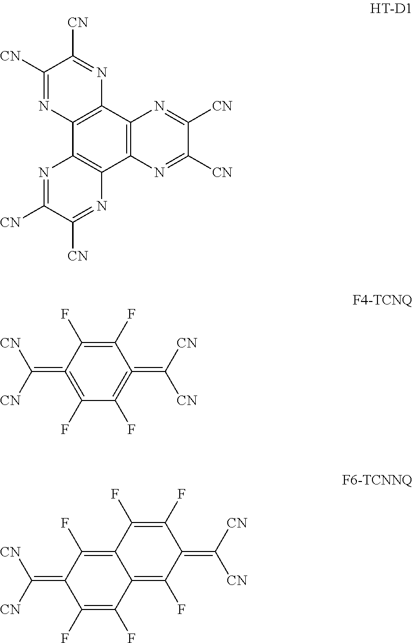

The hole transport region 120 may further include a buffer layer.

The buffer layer may compensate for an optical resonance distance according to a wavelength of light emitted from the emission layer to increase efficiency.

Meanwhile, when the hole transport region 120 includes an electron blocking layer, the material for the electron blocking layer may include a material that may be used in the hole transport region 120 as described above, a host material, or a combination thereof. For example, when the hole transport region 120 includes an electron blocking layer, the material for the electron blocking layer may be mCP or the like.

The emission layer 150 may be formed on the hole transport region 120 by using, for example, a vacuum deposition method, a spin coating method, a cast method, an LB method, and/or an ink-jet printing method.

The emission layer 150 may be as described in connection with the mixed layer 15.

A thickness of the emission layer 150 may be in a range of about 100 Å to about 1,000 Å, for example, about 200 Å to about 600 Å. When the thickness of the emission layer 150 is within these ranges, excellent light-emission characteristics may be obtained without a substantial increase in driving voltage.

When the light-emitting device is a full-color light-emitting device, the emission layer 150 may be patterned into a red emission layer, a green emission layer, and/or a blue emission layer.

Next, the electron transport region 170 may be arranged on the emission layer 150.

The electron transport region 170 may include a hole blocking layer, an electron transport layer, an electron injection layer, or a combination thereof.

For example, the electron transport region 170 may have a hole blocking layer/electron transport layer/electron injection layer structure or an electron transport layer/electron injection layer structure. The electron transport layer may have a single-layered structure or a multi-layered structure including two or more different materials.

The conditions for the forming the hole blocking layer, the electron transport layer, and the electron injection layer in the electron transport region 170 are as the conditions for the forming the hole injection layer.

When the electron transport region 170 includes a hole blocking layer, the hole blocking layer may include, for example, 2,9-dimethyl-4,7-diphenyl-1,10-phenanthroline (BCP), 4,7-diphenyl-1,10-phenanthroline (Bphen),bis(2-methyl-8-quinolinolato-N1,O8)-(1,1′-biphenyl-4-olato)aluminum (BAlq), or a combination thereof:

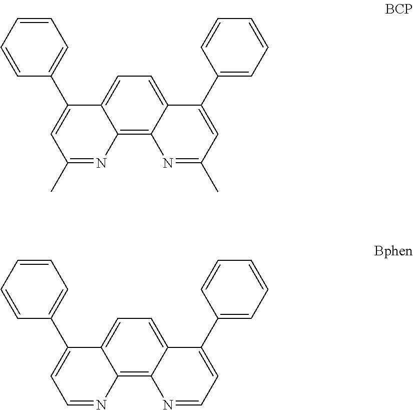 [SMILES: Cc1cc(-c2ccccc2)c2ccc3c(-c4ccccc4)cc(C)nc3c2n1 ; c1ccc(-c2ccnc3c2ccc2c(-c4ccccc4)ccnc23)cc1]

In one or more embodiments, the hole blocking layer may include any host material, and a material for an electron transport layer, a material for an electron injection layer, or a combination thereof, which will be described later.

A thickness of the hole blocking layer may be in a range of about 20 Å to about 1,000 Å, for example, about 30 Å to about 600 Å. When the thickness of the hole block layer is within these ranges, excellent hole blocking characteristics may be obtained without a substantial increase in driving voltage.

The electron transport layer may include BCP, Bphen, 1,3,5-tri(1-phenyl-1H-benzo[d]imidazol-2-yl)phenyl (TPBi), tris(8-hydroxy-quinolinato)aluminum (Alq₃), bis(2-methyl-8-quinolinolato-N1,O8)-(1,1′-biphenyl-4-olato)aluminum (BAlq), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), or a combination thereof:

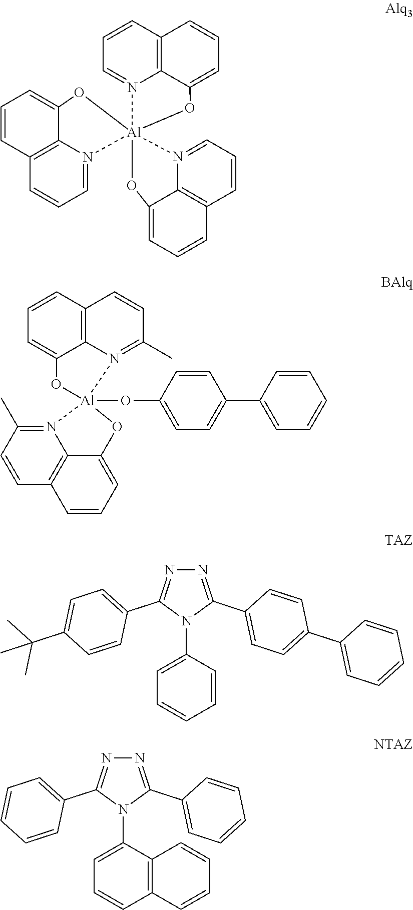

In one or more embodiments, the electron transport layer may include one of Compounds ET1 to ET25 or a combination thereof:

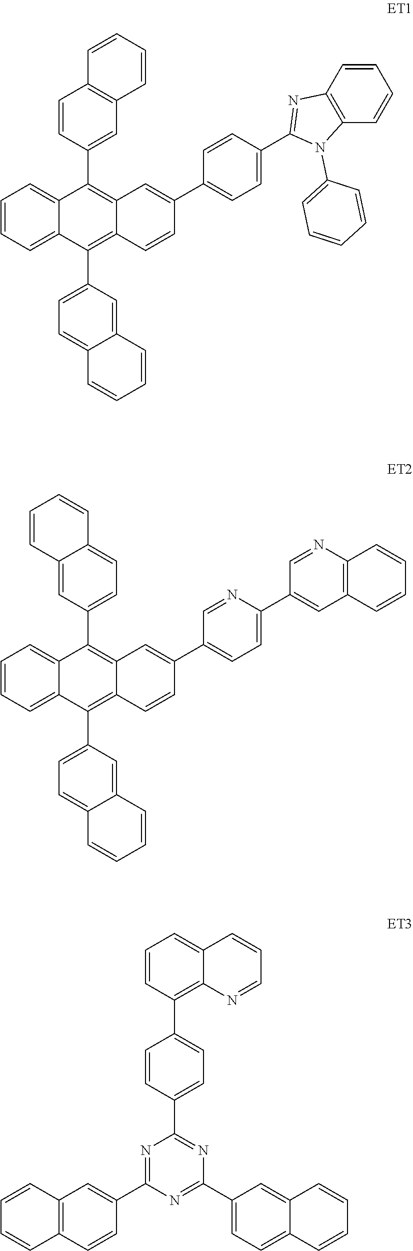 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc2cc(-c3nc(-c4ccc(-c5cccc6cccnc56)cc4)nc(-c4ccc5ccccc5c4)n3)ccc2c1]

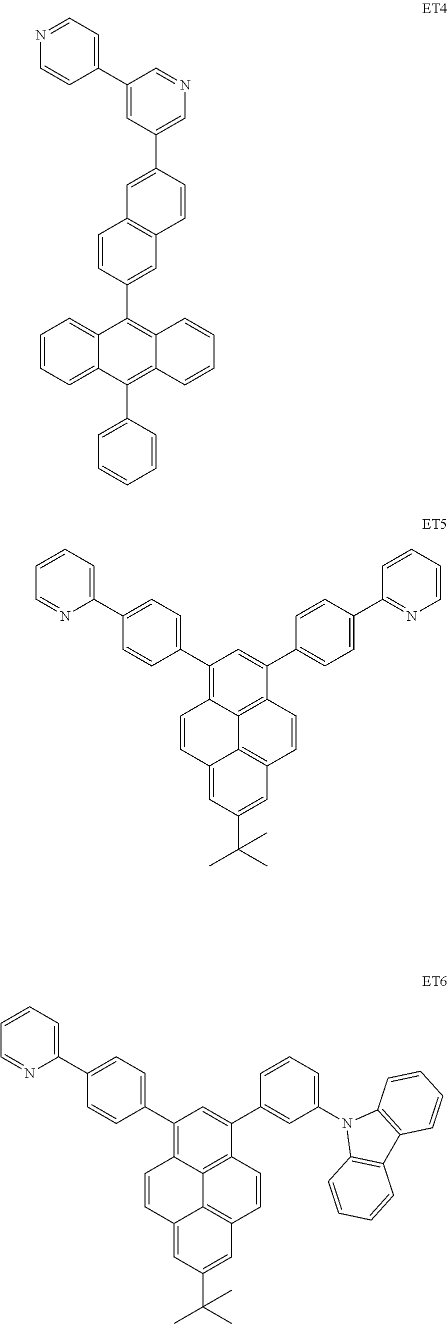 [SMILES: c1ccc(-c2c3ccccc3c(-c3ccc4cc(-c5cncc(-c6ccncc6)c5)ccc4c3)c3ccccc23)cc1 ; CC(C)(C)c1cc2ccc3c(-c4ccc(-c5ccccn5)cc4)cc(-c4ccc(-c5ccccn5)cc4)c4ccc(c1)c2c34 ; CC(C)(C)c1cc2ccc3c(-c4ccc(-c5ccccn5)cc4)cc(-c4cccc(-n5c6ccccc6c6ccccc65)c4)c4ccc(c1)c2c34]

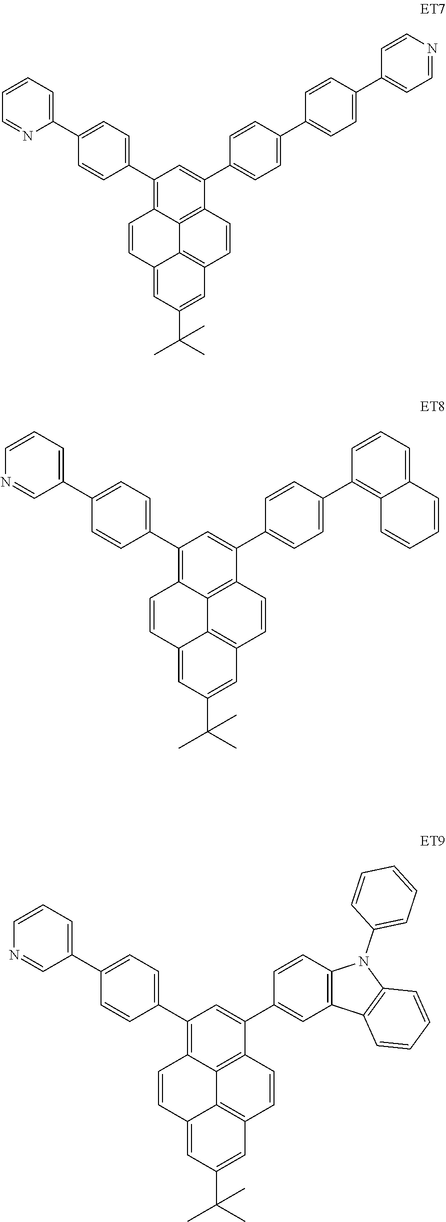 [SMILES: CC(C)(C)c1cc2ccc3c(-c4ccc(-c5ccc(-c6ccncc6)cc5)cc4)cc(-c4ccc(-c5ccccn5)cc4)c4ccc(c1)c2c34 ; CC(C)(C)c1cc2ccc3c(-c4ccc(-c5cccnc5)cc4)cc(-c4ccc(-c5cccc6ccccc56)cc4)c4ccc(c1)c2c34 ; CC(C)(C)c1cc2ccc3c(-c4ccc(-c5cccnc5)cc4)cc(-c4ccc5c(c4)c4ccccc4n5-c4ccccc4)c4ccc(c1)c2c34]

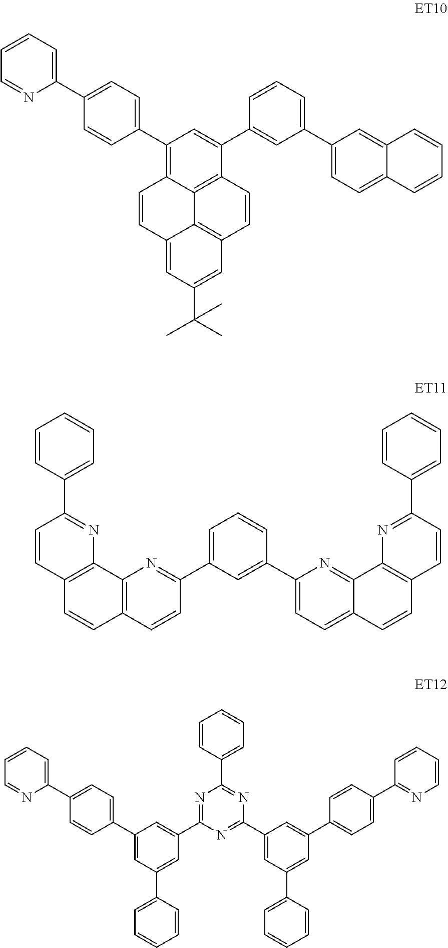 [SMILES: CC(C)(C)c1cc2ccc3c(-c4ccc(-c5ccccn5)cc4)cc(-c4cccc(-c5ccc6ccccc6c5)c4)c4ccc(c1)c2c34 ; c1ccc(-c2ccc3ccc4ccc(-c5cccc(-c6ccc7ccc8ccc(-c9ccccc9)nc8c7n6)c5)nc4c3n2)cc1 ; c1ccc(-c2cc(-c3ccc(-c4ccccn4)cc3)cc(-c3nc(-c4ccccc4)nc(-c4cc(-c5ccccc5)cc(-c5ccc(-c6ccccn6)cc5)c4)n3)c2)cc1]

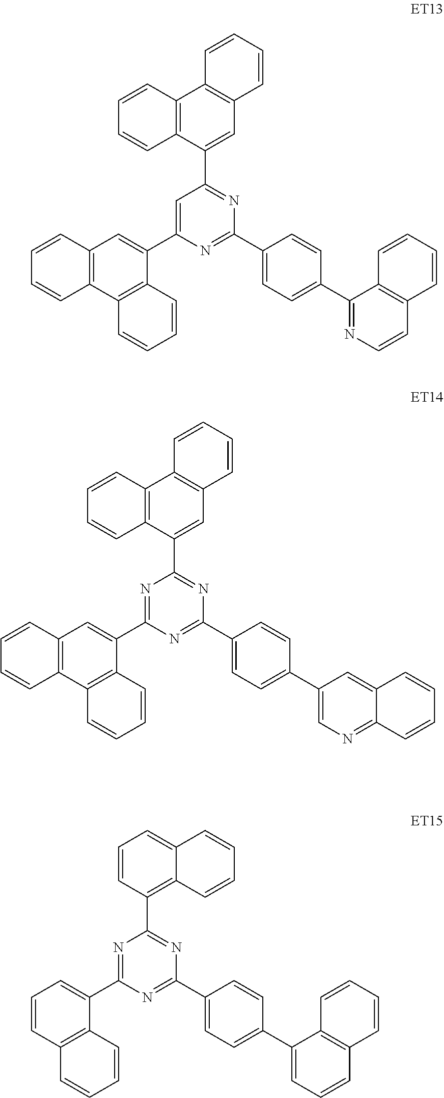 [SMILES: c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1 ; c1ccc2c(-c3ccc(-c4nc(-c5cccc6ccccc56)nc(-c5cccc6ccccc56)n4)cc3)cccc2c1]

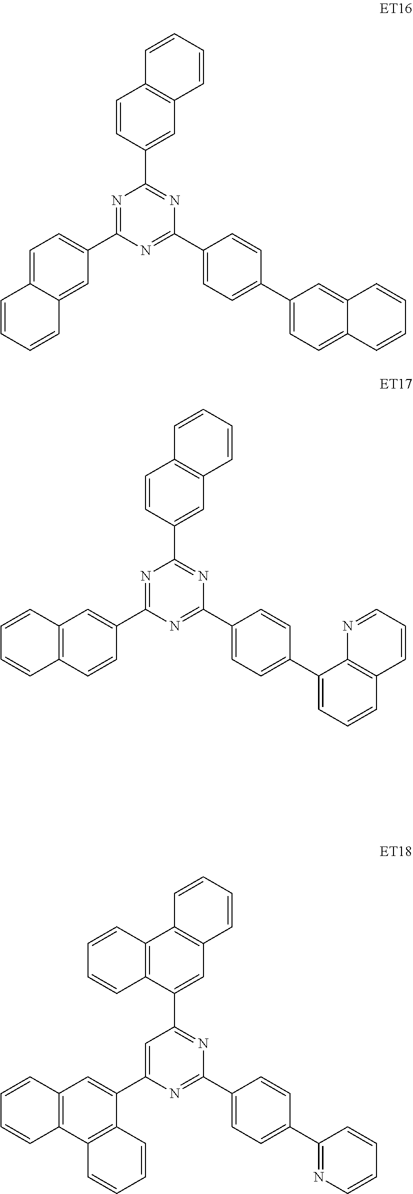 [SMILES: c1ccc2cc(-c3ccc(-c4nc(-c5ccc6ccccc6c5)nc(-c5ccc6ccccc6c5)n4)cc3)ccc2c1 ; c1ccc2cc(-c3nc(-c4ccc(-c5cccc6cccnc56)cc4)nc(-c4ccc5ccccc5c4)n3)ccc2c1 ; c1ccc(-c2ccc(-c3nc(-c4cc5ccccc5c5ccccc45)cc(-c4cc5ccccc5c5ccccc45)n3)cc2)nc1]

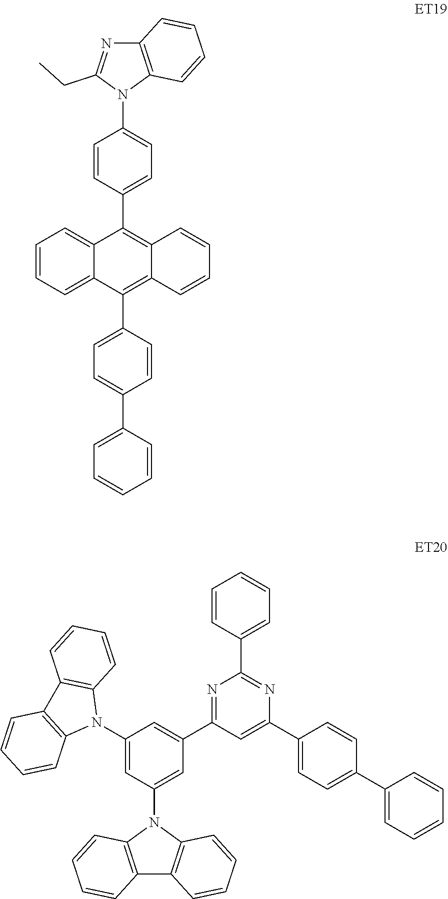 [SMILES: CCc1nc2ccccc2n1-c1ccc(-c2c3ccccc3c(-c3ccc(-c4ccccc4)cc3)c3ccccc23)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1]

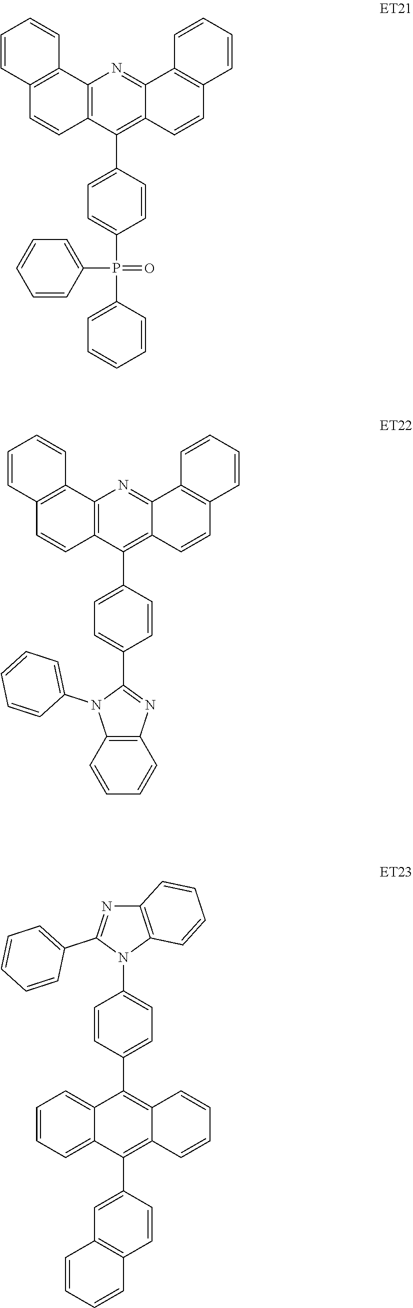 [SMILES: O=P(c1ccccc1)(c1ccccc1)c1ccc(-c2c3ccc4ccccc4c3nc3c2ccc2ccccc23)cc1 ; c1ccc(-n2c(-c3ccc(-c4c5ccc6ccccc6c5nc5c4ccc4ccccc45)cc3)nc3ccccc32)cc1 ; c1ccc(-c2nc3ccccc3n2-c2ccc(-c3c4ccccc4c(-c4ccc5ccccc5c4)c4ccccc34)cc2)cc1]

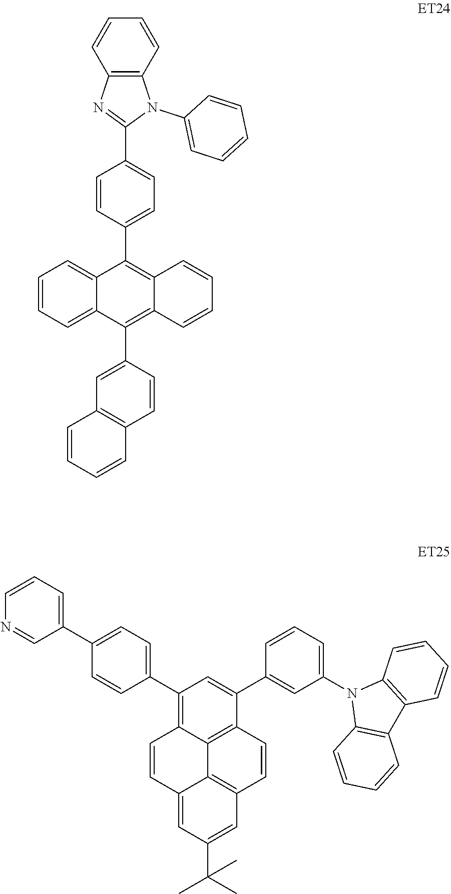 [SMILES: c1ccc(-n2c(-c3ccc(-c4c5ccccc5c(-c5ccc6ccccc6c5)c5ccccc45)cc3)nc3ccccc32)cc1 ; CC(C)(C)c1cc2ccc3c(-c4ccc(-c5cccnc5)cc4)cc(-c4cccc(-n5c6ccccc6c6ccccc65)c4)c4ccc(c1)c2c34]

A thickness of the electron transport layer may be in a range of about 100 Å to about 1,000 Å, for example, about 150 Å to about 500 Å. When the thickness of the electron transport layer is within these ranges, satisfactory electron transporting characteristics may be obtained without a substantial increase in driving voltage.

The electron transport layer may include, in addition to the materials described above, a metal-containing material.

The metal-containing material may include a Li complex. The Li complex may include, for example, Compound ET-D1 or ET-D2:

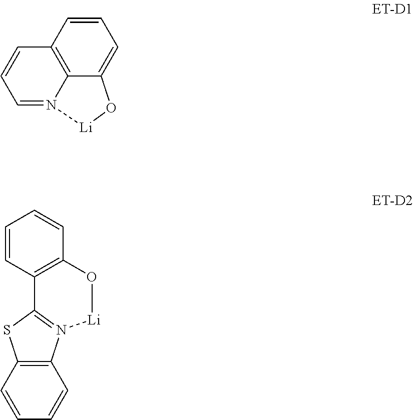

In one or more embodiments, the electron transport region 170 may include an electron injection layer that facilitates injection of electrons from the second electrode 190.

The electron injection layer may include LiF, NaCl, CsF, Li₂O, BaO, Yb, Compound ET-D1, Compound ET-D2, or a combination thereof.

A thickness of the electron injection layer may be in a range of about 1 Å to about 100 Å, for example, about 3 Å to about 90 Å. When the thickness of the electron injection layer is within these ranges, satisfactory electron injection characteristics may be obtained without a substantial increase in driving voltage.

The second electrode 190 may be arranged on the electron transport region 170. The second electrode 190 may be a cathode. A material for forming the second electrode 190 may be metal, an alloy, an electrically conductive compound, or a combination thereof, which have a relatively low work function. For example, lithium (Li), magnesium (Mg), aluminum (Al), silver (Ag), aluminum-lithium (Al—Li), calcium (Ca), magnesium-indium (Mg—In), magnesium-silver (Mg—Ag), or the like may be used as the material for forming the second electrode 190. In one or more embodiments, to manufacture a top-emission type light-emitting device, a transparent or semi-transparent electrode formed using ITO or IZO may be used as the second electrode 190.

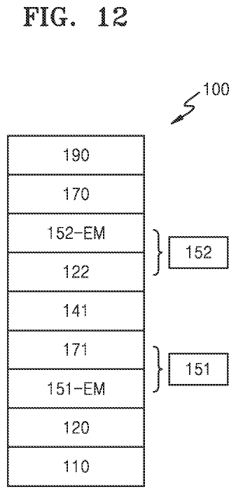

### Description of FIG. 12

FIG. 12 is a diagram schematically illustrating a cross-section of a light-emitting device 100 according to one or more embodiments.

The light-emitting device 100 in FIG. 12 includes a first electrode 110, a second electrode 190 facing the first electrode 110, and a first light-emitting unit 151 and a second light-emitting unit 152 stacked between the first electrode 110 and the second electrode 190. A charge generation layer 141 is arranged between the first light-emitting unit 151 and the second light-emitting unit 152. The charge generation layer 141 may include an n-type charge generation layer, a p-type charge generation layer, or a combination thereof. The charge generation layer 141 is a layer that generates charge and supplies the charge to neighboring light-emitting units, and any known material may be used therefor.

The first light-emitting unit 151 may include a first emission layer 151-EM, and the second light-emitting unit 152 may include a second emission layer 152-EM. At least one of the first emission layer 151-EM and the second emission layer 152-EM may be the mixed layer 15 described herein.

A hole transport region 120 is arranged between the first light-emitting unit 151 and the first electrode 110, and the second light-emitting unit 152 includes a second hole transport region 122 arranged on the side of the first electrode 110.

An electron transport region 170 is arranged between the second light-emitting unit 152 and the second electrode 190, and the first light-emitting unit 151 includes a first electron transport region 171 arranged between the charge generation layer 141 and the first emission layer 151-EM.

The first electrode 110 and the second electrode 190 in FIG. 12 may be as described in connection with the first electrode 110 and the second electrode 190 in FIG. 1.

The hole transport region 120 and the second hole transport region 122 in FIG. 12 may each be as described in connection with the hole transport region 120 in FIG. 11.

The electron transport region 170 and the first electron transport region 171 in FIG. 12 may each be as described in connection with the electron transport region 170 in FIG. 11.

Hereinbefore, one or more embodiments of a tandem light-emitting device has been described with reference to FIG. 12, but the tandem light-emitting device may have various modifications. For example, the tandem light-emitting device may include three or more light-emitting units.

### Explanation of Terms

The term “C₁-C₆₀ alkyl group” as used herein refers to a linear or branched saturated aliphatic hydrocarbons monovalent group having 1 to 60 carbon atoms, and the term “C₁-C₆₀ alkylene group” as used here refers to a divalent group having the same structure as the C₁-C₆₀ alkyl group.

Examples of the C₁-C₆₀ alkyl group, the C₁-C₂₀ alkyl group, and/or the C₁-C₁₀ alkyl group may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, or a tert-decyl group, each unsubstituted or substituted with a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, or a combination thereof. For example, Formula 9-33 is a branched C₆ alkyl group, for example, a tert-butyl group that is substituted with two methyl groups.

The term “C₁-C₆₀ alkoxy group” as used herein refers to a monovalent group represented by —OA₁₀₁ (wherein A₁₀₁ is the C₁-C₆₀ alkyl group), and examples thereof include a methoxy group, an ethoxy group, a propoxy group, a butoxy group, and a pentoxy group.

The term “C₁-C₆₀ alkylthio group” as used herein refers to a monovalent group having the formula of —SA_{1,1} (wherein A₁₀₁ is the C₁-C₆₀ alkyl group).

The term “C₂-C₆₀ alkenyl group” as used herein refers to a hydrocarbon group formed by substituting at least one carbon-carbon double bond in the middle or at the terminus of the C₂-C₆₀ alkyl group, and examples thereof include an ethenyl group, a propenyl group, and a butenyl group. The term “C₂-C₆₀ alkenylene group” as used herein refers to a divalent group having the same structure as the C₂-C₆₀ alkenyl group.

The term “C₂-C₆₀ alkynyl group” as used herein refers to a hydrocarbon group formed by substituting at least one carbon-carbon triple bond in the middle or at the terminus of the C₂-C₆₀ alkyl group, and examples thereof include an ethynyl group, and a propynyl group. The term “C₂-C₆₀ alkynylene group” as used herein refers to a divalent group having the same structure as the C₂-C₆₀ alkynyl group.

The term “C₃-C₁₀ cycloalkyl group” as used herein refers to a monovalent saturated hydrocarbon cyclic group having 3 to 10 carbon atoms, and the term “C₃-C₁₀ cycloalkylene group” as used herein refers to a divalent group having the same structure as the C₃-C₁₀ cycloalkyl group.

Examples of the C₃-C₁₀ cycloalkyl group may include a cyclopropyl group, a cyclobutyl group, a cyclopentyl, cyclohexyl group, a cycloheptyl group, a cyclooctyl group, an adamantanyl group, a norbornanyl group (or a bicyclo[2.2.1]heptyl group), a bicyclo[1.1.1]pentyl group, a bicyclo[2.1.1]hexyl group, and a bicyclo[2.2.2]octyl group.

The term “C₁-C₁₀ heterocycloalkyl group” as used herein refers to a monovalent saturated cyclic group that includes at least one heteroatom selected from N, O, P, Si, S, Se, Ge, and B as a ring-forming atom and 1 to 10 carbon atoms, and the term “C₁-C₁₀ heterocycloalkylene group” as used herein refers to a divalent group having the same structure as the C₁-C₁₀ heterocycloalkyl group.

Examples of the C₁-C₁₀ heterocycloalkyl group may include a silolanyl group, a silinanyl group, tetrahydrofuranyl group, a tetrahydro-2H-pyranyl group, and a tetrahydrothiophenyl group.

The term “C₃-C₁₀ cycloalkenyl group” as used herein refers to a monovalent monocyclic group that has 3 to 10 carbon atoms and at least one carbon-carbon double bond in the ring thereof and no aromaticity, and examples thereof include a cyclopentenyl group, a cyclohexenyl group, and a cycloheptenyl group. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent monocyclic group that has at least one heteroatom selected from N, O, P, Si, S, Se, Ge, and B as a ring-forming atom, 1 to 10 carbon atoms, and at least one double bond in its ring. Examples of the C₁-C₁₀ heterocycloalkenyl group include a 2,3-dihydrofuranyl group and a 2,3-dihydrothiophenyl group. The term “C₁-C₁₀ heterocycloalkenylene group” as used herein refers to a divalent group having the same structure as the C₁-C₁₀ heterocycloalkenyl group.

The term “C₆-C₆₀ aryl group” as used herein refers to a monovalent group having a carbocyclic aromatic system having 6 to 60 carbon atoms, and the term “C₆-C₆₀ arylene group” as used herein refers to a divalent group having a carbocyclic aromatic system having 6 to 60 carbon atoms. Examples of the C₆-C₆₀ aryl group include a phenyl group, a naphthyl group, an anthracenyl group, a phenanthrenyl group, a pyrenyl group, and a chrysenyl group. When the C₆-C₆₀ aryl group and the C₆-C₆₀ arylene group each include two or more rings, the two or more rings may be fused to each other.

The term “C₇-C₆₀ alkyl aryl group” as used herein refers to a C₆-C₆₀ aryl group substituted with at least one C₁-C₆₀ alkyl group.

The term “C₇-C₆₀ aryl alkyl group” as used herein refers to a C₁-C₆₀ alkyl group substituted with at least one C₆-C₆₀ aryl group.

The term “C₁-C₆₀ heteroaryl group” as used herein refers to a monovalent group that includes at least one heteroatom selected from N, O, P, Si, S, Se, Ge, and B as a ring-forming atom and a cyclic aromatic system having 1 to 60 carbon atoms, and the term “C₁-C₆₀ heteroarylene group” as used herein refers to a divalent group that includes at least one heteroatom selected from N, O, P, Si, S, Se, Ge, and B as a ring-forming atom and a carbocyclic aromatic system having 1 to 60 carbon atoms. Examples of the C₁-C₆₀ heteroaryl group include a pyridinyl group, a pyrimidinyl group, a pyrazinyl group, a pyridazinyl group, a triazinyl group, a quinolinyl group, and an isoquinolinyl group. When the C₆-C₆₀ heteroaryl group and the C₆-C₆₀ heteroarylene group each include two or more rings, the two or more rings may be fused to each other.

The term “C₂-C₆₀ alkyl heteroaryl group” as used herein refers to a C₁-C₆₀ heteroaryl group substituted with at least one C₁-C₆₀ alkyl group.

The term “C₂-C₆₀ heteroaryl alkyl group” as used herein refers to a C₁-C₆₀ alkyl group substituted with at least one C₁-C₆₀ heteroaryl group.

The term “C₆-C₆₀ aryloxy group” as used herein indicates —OA₁₀₂ (wherein A10₂ is the C₆-C₆₀ aryl group), and the term “C₆-C₆₀ arylthio group” as used herein indicates —SA₁₀₃ (wherein A₁₀₃ is the C₆-C₆₀ aryl group).

The term “monovalent non-aromatic condensed polycyclic group” as used herein refers to a monovalent group (for example, having 8 to 60 carbon atoms) having two or more rings condensed to each other, only carbon atoms as ring-forming atoms, and no aromaticity in its entire molecular structure. Examples of the monovalent non-aromatic condensed polycyclic group include a fluorenyl group. The term “divalent non-aromatic condensed polycyclic group” as used herein refers to a divalent group having the same structure as the monovalent non-aromatic condensed polycyclic group.

The term “monovalent non-aromatic condensed heteropolycyclic group” as used herein refers to a monovalent group (for example, having 1 to 60 carbon atoms) having two or more rings condensed to each other, at least one heteroatom selected from N, O, P, Si, S, Se, Ge, and B, other than carbon atoms, as a ring-forming atom, and no aromaticity in its entire molecular structure. Examples of the monovalent non-aromatic condensed heteropolycyclic group include a carbazolyl group. The term “divalent non-aromatic condensed heteropolycyclic group” as used herein refers to a divalent group having the same structure as the monovalent non-aromatic condensed heteropolycyclic group.

The term “C₅-C₃₀ carbocyclic group” as used herein refers to a saturated or unsaturated cyclic group including 5 to 30 carbon atoms only as ring-forming atoms. The C₅-C₃₀ carbocyclic group may be a monocyclic group or a polycyclic group. Examples of the “C₅-C₃₀ carbocyclic group (unsubstituted or substituted with at least one R₁₀ₐ)” as used herein may include an adamantane group, a norbornene group, a bicyclo[1.1.1]pentane group, a bicyclo[2.1.1]hexane group, a bicyclo[2.2.1]heptane(norbornane) group, a bicyclo[2.2.2]octane group, a cyclopentane group, a cyclohexane group, a cyclohexene group, a benzene group, a naphthalene group, an anthracene group, a phenanthrene group, a triphenylene group, a pyrene group, a chrysene group, a 1,2,3,4-tetrahydronaphthalene group, a cyclopentadiene group, and a fluorene group (each unsubstituted or substituted with at least one R₁₀ₐ).

The term “C₁-C₃₀ heterocyclic group” as used herein refers to a saturated or unsaturated cyclic group having, as a ring-forming atom, at least one heteroatom selected from N, O, P, Si, S, Se, Ge, and B other than 1 to 30 carbon atoms. The C₁-C₃₀ heterocyclic group may be a monocyclic group or a polycyclic group. Examples of the “C₁-C₃₀ heterocyclic group (unsubstituted or substituted with at least one R₁₀ₐ)” as used herein may include a thiophene group, a furan group, a pyrrole group, a silole group, borole group, a phosphole group, a selenophene group, a germole group, a benzothiophene group, a benzofuran group, an indole group, a benzosilole group, a benzoborole group, a benzophosphole group, a benzoselenophene group, a benzogermole group, a dibenzothiophene group, a dibenzofuran group, a carbazole group, a dibenzosilole group, a dibenzoborole group, a dibenzophosphole group, a dibenzoselenophene group, a dibenzogermole group, a dibenzothiophene 5-oxide group, a 9H-fluoren-9-one group, a dibenzothiophene 5,5-dioxide group, an azabenzothiophene group, an azabenzofuran group, an azaindole group, an azaindene group, an azabenzosilole group, an azabenzoborole group, an azabenzophosphole group, an azabenzoselenophene group, an azabenzogermole group, an azadibenzothiophene group, an azadibenzofuran group, an azacarbazole group, an azafluorene group, an azadibenzosilole group, an azadibenzoborole group, an azadibenzophosphole group, an azadibenzoselenophene group, an azadibenzogermole group, an azadibenzothiophene 5-oxide group, an aza-9H-fluoren-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrazole group, an imidazole group, a triazole group, an oxazole group, an isooxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, and a 5,6,7,8-tetrahydroquinoline group (each unsubstituted or substituted with at least one R₁₀ₐ).

In one or more embodiments, examples of the “C₅-C₃₀ carbocyclic group” and “C₁-C₃₀ heterocyclic group” as used herein include i) a first ring, ii) a second ring, iii) a condensed ring in which two or more first rings are condensed with each other, iv) a condensed ring in which two or more second rings are condensed with each other, or v) a condensed ring in which at least one first ring and at least one second ring are condensed with each other,
the first ring may be a cyclopentane group, a cyclopentene group, a furan group, a thiophene group, a pyrrole group, a silole group, a borole group, a phosphole group, a germole group, a selenophene group, an oxazole group, an oxadiazole group, an oxatriazole group, a thiazole group, a thiadiazole group, a thiatriazole group, a pyrazole group, an imidazole group, a triazole group, a tetrazole group, or an azasilole group, and the second ring may be an adamantane group, a norbornane group, a norbornene group, a cyclohexane group, a cyclohexene group, a benzene group, a pyridine group, a pyrimidine group, a pyrazine group, a pyridazine group, or a triazine group.

The terms “fluorinated C₁-C₆₀ alkyl group (or, a fluorinated C₁-C₂₀ alkyl group or the like)”, “fluorinated C₃-C₁₀ cycloalkyl group”, “fluorinated C₁-C₁₀ heterocycloalkyl group,” and “fluorinated phenyl group” as used herein respectively refer to a C₁-C₆₀ alkyl group (or, a C₁-C₂₀ alkyl group or the like), a C₃-C₁₀ cycloalkyl group, a C₁-C₁₀ heterocycloalkyl group, and a phenyl group, each substituted with at least one fluoro group. For example, the term “fluorinated C₁ alkyl group (that is, a fluorinated methyl group)” includes —CF₃, —CF₂H, and —CFH₂. The “fluorinated C₁-C₆₀ alkyl group (or, a fluorinated C₁-C₂₀ alkyl group or the like)”, “the fluorinated C₃-C₁₀ cycloalkyl group”, “the fluorinated C₁-C₁₀ heterocycloalkyl group”, or “the fluorinated a phenyl group” may be i) a fully fluorinated C₁-C₆₀ alkyl group (or, a fully fluorinated C₁-C₂₀ alkyl group or the like), a fully fluorinated C₃-C₁₀ cycloalkyl group, a fully fluorinated C₁-C₁₀ heterocycloalkyl group, or a fully fluorinated phenyl group, wherein, in each group, all hydrogen included therein is substituted with a fluoro group, or ii) a partially fluorinated C₁-C₆₀ alkyl group (or, a partially fluorinated C₁-C₂₀ alkyl group or the like), a partially fluorinated C₃-C₁₀ cycloalkyl group, a partially fluorinated C₁-C₁₀ heterocycloalkyl group, or a partially fluorinated phenyl group, wherein, in each group, not all hydrogen included therein is substituted with a fluoro group.

The terms “deuterated C₁-C₆₀ alkyl group (or, a deuterated C₁-C₂₀ alkyl group or the like)”, “deuterated C₃-C₁₀ cycloalkyl group”, “deuterated C₁-C₁₀ heterocycloalkyl group,” and “deuterated phenyl group” as used herein respectively refer to a C₁-C₆₀ alkyl group (or, a C₁-C₂₀ alkyl group or the like), a C₃-C₁₀ cycloalkyl group, a C₁-C₁₀ heterocycloalkyl group, and a phenyl group, each substituted with at least one deuterium. For example, the “deuterated C₁ alkyl group (that is, a deuterated methyl group)” may include —CD₃, —CD₂H, and —CDH₂, and examples of the “deuterated C₃-C₁₀ cycloalkyl group” are, for example, Formula 10-501 and the like. The “deuterated C₁-C₆₀ alkyl group (or, the deuterated C₁-C₂₀ alkyl group or the like)”, “the deuterated C₃-C₁₀ cycloalkyl group”, “the deuterated C₁-C₁₀ heterocycloalkyl group”, or “the deuterated phenyl group” may be i) a fully deuterated C₁-C₆₀ alkyl group (or, a fully deuterated C₁-C₂₀ alkyl group or the like), a fully deuterated C₃-C₁₀ cycloalkyl group, a fully deuterated C₁-C₁₀ heterocycloalkyl group, or a fully deuterated phenyl group, in which, in each group, all hydrogen included therein are substituted with deuterium, or ii) a partially deuterated C₁-C₆₀ alkyl group (or, a partially deuterated C₁-C₂₀ alkyl group or the like), a partially deuterated C₃-C₁₀ cycloalkyl group, a partially deuterated C₁-C₁₀ heterocycloalkyl group, or a partially deuterated phenyl group, in which, in each group, not all hydrogen included therein are substituted with deuterium.

The term “(C₁-C₂₀ alkyl) ‘X’ group” as used herein refers to a ‘X’ group that is substituted with at least one C₁-C₂₀ alkyl group. For example, the term “(C₁-C₂₀ alkyl)C₃-C₁₀ cycloalkyl group” as used herein refers to a C₃-C₁₀ cycloalkyl group substituted with at least one C₁-C₂₀ alkyl group, and the term “(C₁-C₂₀ alkyl)phenyl group” as used herein refers to a phenyl group substituted with at least one C₁-C₂₀ alkyl group. An example of the term “(C₁ alkyl)phenyl group” is a toluyl group.

The terms “an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluoren-9-one group, and an azadibenzothiophene 5,5-dioxide group” respectively refer to heterocyclic groups having the same backbones as “an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluoren-9-one group, and a dibenzothiophene 5,5-dioxide group,” in which, in each group, at least one carbon selected from ring-forming carbons is substituted with nitrogen.

At least one substituent of the substituted C₅-C₃₀ carbocyclic group, the substituted C₁-C₃₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ alkyl aryl group, the substituted C₇-C₆₀ aryl alkyl group, the substituted C₆-C₆₀ aryloxy group, the substituted C₆-C₆₀ arylthio group, the substituted C₁-C₆₀ heteroaryl group, the substituted C₂-C₆₀ alkyl heteroaryl group, the substituted C₂-C₆₀ heteroaryl alkyl group, the substituted C₁-C₆₀ heteroaryloxy group, the substituted C₁-C₆₀ heteroarylthio group, the substituted monovalent non-aromatic condensed polycyclic group, and the substituted monovalent non-aromatic condensed heteropolycyclic group may be:
deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group;
a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, each substituted with at least one of deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or a combination thereof;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, or a monovalent non-aromatic condensed heteropolycyclic group, each unsubstituted or substituted with at least one of deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or a combination thereof;
—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉); or
a combination thereof.

Q₁ to Q₉, Q₁₁ to Q₁₉, Q₂₁ to Q₂₉, and Q₃₁ to Q₃₉ as used herein may each independently be:
hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₇-C₆₀ aryl alkyl group, a C₁-C₆ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, or a monovalent non-aromatic condensed heteropolycyclic group, each unsubstituted or substituted with at least one of deuterium, a C₁-C₆₀ alkyl group, a C₆-C₆₀ aryl group, or a combination thereof.

For example, Q₁ to Q, Q₁₁ to Q₁₉, Q₂₁ to Q₂₉, and Q₃₁ to Q₃₉ as used herein may each independently be:
—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂, or

an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, a phenyl group, a biphenyl group, or a naphthyl group, each unsubstituted or substituted with at least one of deuterium, a C₁-C₁₀ alkyl group, a phenyl group, or a combination thereof.

### EXAMPLES

### Evaluation Example 1 (Evaluation of Melting Point and/or Fusion Temperature)

The melting point and/or fusion temperature of each of Pre-mixed composition A1, Pre-mixed composition A2, Ir-1, and Pt-1 were evaluated, and the results thereof are summarized in Table 1. Pre-mixed composition A1 is a composition prepared by physically mixing Ir-1 and Pt-1 at a weight ratio of 1:1, and pre-mixed composition A2 is a composition prepared by solidifying Ir-1 and Pt-1 after sublimation and purification at a weight ratio of 1:1. The melting point was measured using a DSC evaluation device of TA Instruments Inc., and the fusion temperature was measured using a melting point measuring device of BUCHI Inc.

TABLE 1

| | Pre-mixed | Pre-mixed | | |
|---|---|---|---|---|
| | composition | composition | | |
| | A1 | A2 | Ir-1 | Pt-1 |
| Melting | 305 | N.D. | 388 | 326 |
| point (° C.) | | (amorphous) | | |
| Fusion | 302 | 247 | 387 | 325 |
| temperature | | (the temperature at which the | | |
| (° C.) | | volume changed after heating | | |
| | | was measured) | | |

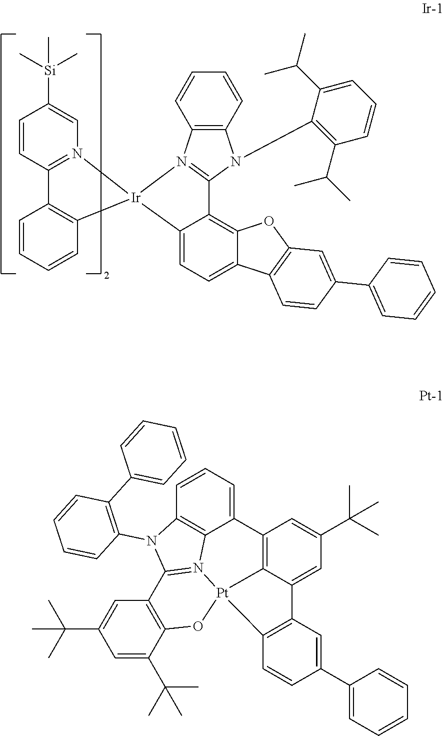

Referring to Table 1, it was confirmed that the melting point of Pre-mixed composition A1 and the fusion temperature of Pre-mixed composition A2 were lower than the melting points of Ir-1 and Pt-1, respectively.

### Evaluation Example 2 (Evaluation of Heat Resistance)

The purity of each of Pre-mixed composition A1, Ir-1, and Pt-1 was evaluated using high performance liquid chromatography (HPLC), and the results thereof are summarized in Table 2.

Next, each of Pre-mixed composition A1, Ir-1, and Pt-1 was heated for 300 hours in a chamber maintained at a vacuum degree of 1.2×10⁻² torr and an internal temperature of 310° C., and then collected and subjected again to purity evaluation using the HPLC. The results thereof are summarized in Table 2.

TABLE 2

| | | Purity before | Purity after |
|---|---|---|---|
| | | heating (%) | heating (%) |
| Pt-1 | | 99.75 | 99.65 |
| Ir-1 | | 99.17 | 99.16 |
| Pre-mixed | Pt-1 | 55 | 5.09 |
| composition A1 | Ir-1 | 45 | 67 |

Referring to Table 2, it was confirmed that Pt-1 and Ir-1, which have melting points higher than 310° C., showed little change in purity before and after heating, and thus were substantially free from thermal denaturation due to heating at 310° C. for 300 hours.

However, pre-mixed composition A1, which has a melting point lower than 310° C., showed a significant change in purity before and after heating, and thus, it was confirmed that a significant amount of Pt-1 and/or Ir-1 included in pre-mixed composition A1 was decomposed due to thermal denaturation due to heating at 310° C. for 300 hours.

### Manufacture of OLED 1

As an anode, an ITO-patterned glass substrate was cut to a size of 50 millimeters (mm)×50 mm×0.5 mm, sonicated with isopropyl alcohol and pure water, each for 5 minutes, and then cleaned by exposure to ultraviolet rays and ozone for 30 minutes. The resultant glass substrate was loaded onto a vacuum deposition apparatus.

HT3 and F6-TCNNQ were vacuum-co-deposited on the anode at a weight ratio of 98:2 to form a hole injection layer having a thickness of 100 Å, and HT3 was vacuum-deposited on the hole injection layer to form a hole transport layer having a thickness of 1,350 Å. H-H1 was vacuum-deposited on the hole transport layer to form an electron blocking layer having a thickness of 300 Å.

Next, a host and a dopant were co-deposited at a weight ratio of 88:12 on the electron blocking layer to form an emission layer having a thickness of 400 Å. As the host, H-H1 and H-H2 were used at a weight ratio of 5:5, and as the dopant, Pt-1 and Ir-1 were used at a weight ratio of 1:1.

The emission layer was formed by performing the reciprocating process of the deposition source moving unit 350 described with reference to FIGS. 2A to 2G two consecutive times by using the first deposition source 300 as described herein. Here, as Pt-1 and Ir-1, Pt-1 and Ir-1 collected after the heat resistance evaluation of Evaluation Example 2 were used, wherein Pt-1 and Ir-1 were not mixed with each other in the first deposition source 300, and a vapor-state composition formed by mixing vapor-state Pt-1 and vapor-state Ir-1 released from the first deposition source 300 was deposited together with a vapor-state host.

Then, ET3 and ET-D1 were co-deposited at a volume ratio of 50:50 on the emission layer to form an electron transport layer having a thickness of 350 Å, ET-D1 was vacuum-deposited on the electron transport layer to form an electron injection layer having a thickness of 10 Å, and A1 was vacuum-deposited on the electron injection layer to form a cathode having a thickness of 1,000 Å, thereby completing the manufacture of a light-emitting device.

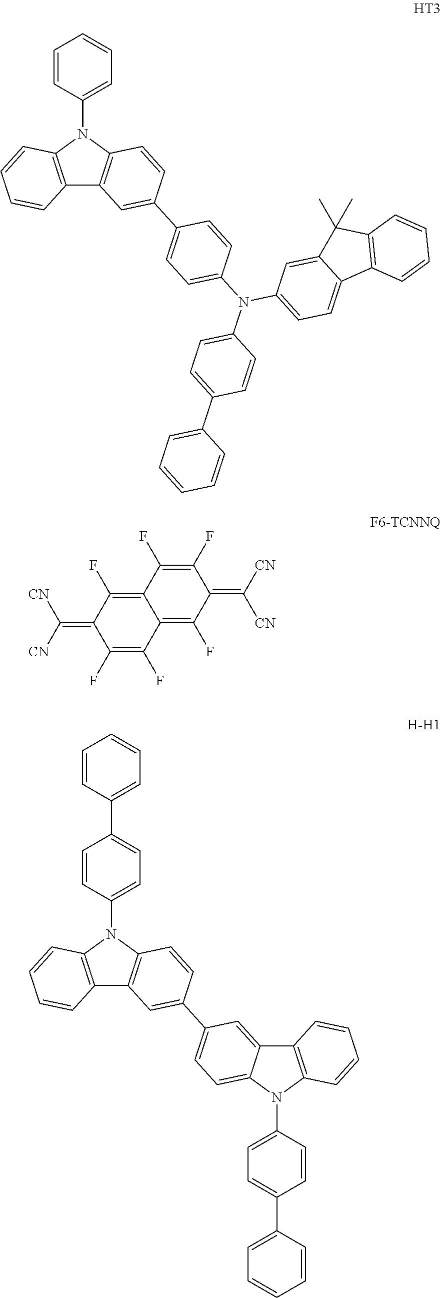

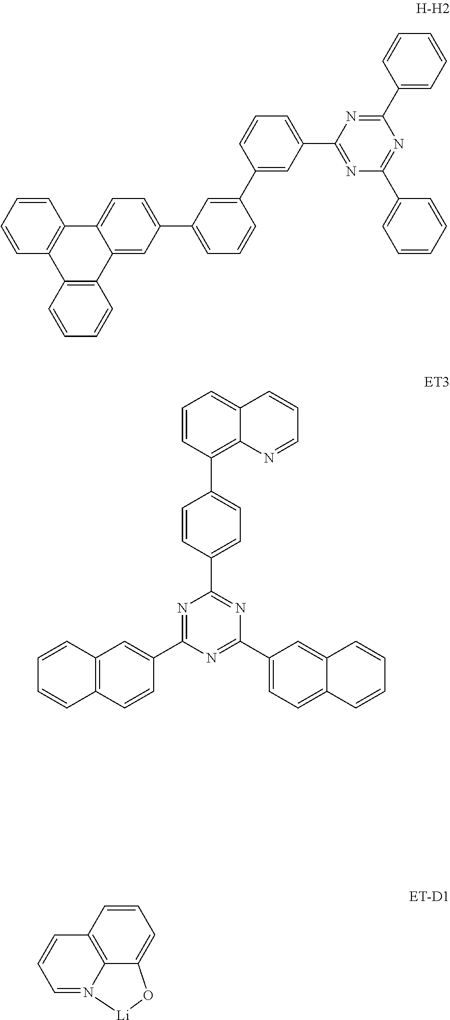

### Manufacture of OLED A

OLED A was manufactured in a similar manner as used to manufacture OLED 1, except that, in forming an emission layer, Pre-mixed composition A1 collected after the heat resistance evaluation of Evaluation Example 2 was used instead of Pt-1 and Ir-1 collected after the heat resistance evaluation of Evaluation Example 2.

### Manufacture of OLED B

OLED B was manufactured in a similar manner as used to manufacture OLED 1, except that, in forming an emission layer, the deposition source B1 loaded with Pt-1 and the deposition source B2 loaded with Ir-1 were each used instead of the first deposition source 300 in which Pt-1 and Ir-1 are not mixed with each other.

### Evaluation Example 3: Evaluation of Device Characteristics

The driving voltage (Volts, V), the external quantum luminescence efficiency (EQE, %), and the lifespan (T₉₇, %) of each of OLED 1, OLED A, and OLED B were evaluated, and the results thereof are shown in Table 3. As evaluation devices, a current-voltmeter (Keithley 2400) and a luminance meter (Minolta Cs-1000A) were used, and the lifespan (T₉₇) (at 16,000 candela per square meter, or nits) was evaluated as the time taken for luminance to be reduced to 97% of the initial luminance of 100%.

TABLE 3

| | | | External | |
|---|---|---|---|---|
| | | | quantum | Lifespan |
| | Dopant deposition | Driving | Luminescence | (T₉₇) |
| | source used in forming | voltage | efficiency | (at 16,000 |
| | emission layer | (V) | (%) | cd/m²) |
| OLED 1 | First deposition source | 4.0 | 24.4 | 100% |
| | 300 as described in | | | |
| | FIG. 2A, including | | | |
| | Pt-1 and Ir-1 not | | | |
| | mixed with each other | | | |
| OLED A | Pre-mixed composition | 3.94 | 23.8 | 5% |
| | A1 collected after | | | |
| | heat resistance | | | |
| | evaluation of | | | |
| | Evaluation Example 2 | | | |
| OLED B | Deposition source | 4.1 | 23.0 | 50% |
| | B1 loaded with Pt-1 | | | |
| | and Deposition | | | |
| | source B2 loaded | | | |
| | with Ir-1 | | | |

Referring to Table 3, it was confirmed that OLED 1 had a driving voltage equal to or higher than those of OLED A and OLED B, and showed improved external quantum luminescence efficiency and lifetime characteristics compared to those of OLED A and OLED B. In detail, from the device data of OLED A, it is determined that when the heating conditions of 310° C. for 300 hours are the desired deposition temperature and deposition time conditions, it is not suitable to use Pre-mixed composition A1 as a deposition object, and, in order to perform a deposition process without thermal denaturation of Pt-1 and Ir-1 while using Pre-mixed composition A1 as the deposition object, it is necessary to select a deposition temperature that is lower than the melting point of Pre-mixed composition A1.

In the mixed layer as described above, a first dopant and a second dopant are effectively doped at substantially the same time (e.g., at the same time) without thermal denaturation. Accordingly, a light-emitting device including the mixed layer may have excellent luminescence efficiency and/or a long lifespan. By using the light-emitting device, a high-quality electronic apparatus may be manufactured. In addition, the method of preparing a mixed layer as described above may provide excellent process stability and reduction of manufacturing costs. Accordingly, by using the method of preparing a mixed layer, high-quality light-emitting devices and electronic apparatuses may be economically manufactured in large quantities.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A mixed layer, comprising:
a matrix material; and
a dopant composition,
wherein the dopant composition is doped in the matrix material,
wherein the dopant composition comprises a first dopant and a second dopant,
an amount by weight of the matrix material in the mixed layer is greater than an amount by weight of the dopant composition in the mixed layer,
the matrix material, the first dopant, and the second dopant are different from each other,
the matrix material does not comprise a transition metal,
the first dopant comprises a transition metal,
the mixed layer is a layer formed by deposition of the matrix material, the first dopant, and the second dopant,
the mixed layer has a concentration profile of the dopant composition with respect to a thickness of the mixed layer,
provided that Tₘ₁>Tₚ>Tₘ₁₊₂ is satisfied,
wherein,
Tₘ₁ is a melting point of the first dopant,
Tₚ is a deposition temperature used in forming the mixed layer, and
Tₘ₁₊₂ is
a melting point of a pre-mixed composition of the first dopant and the second dopant, wherein the pre-mixed composition is crystalline; and
a fusion temperature of the pre-mixed composition of the first dopant and the second dopant, wherein the pre-mixed composition is amorphous,
wherein the pre-mixed composition comprises the first dopant and the second dopant, and is not doped in the matrix material.

2. The mixed layer of claim 1, wherein the matrix material comprises a hole-transporting compound, an electron-transporting compound, a bipolar compound, or a combination thereof.

3. The mixed layer of claim 1, wherein the first dopant comprises iridium or platinum.

4. The mixed layer of claim 1, wherein the mixed layer is a layer formed by deposition of a vapor-state matrix material and a vapor-state dopant composition, and
the vapor-state dopant composition comprises a vapor-state first dopant and a vapor-state second dopant.

5. The mixed layer of claim 1, wherein the second dopant comprises a transition metal.

6. The mixed layer of claim 1, wherein the second dopant comprises iridium or platinum.

7. The mixed layer of claim 5, wherein Tₘ₂>Tₚ is satisfied,
Tₚ is as described in claim 1, and
Tₘ₂ is a melting point of the second dopant.

8. The mixed layer of claim 1, wherein the second dopant does not comprise a transition metal.

9. The mixed layer of claim 1, wherein the second dopant comprises a cyclic group including a boron atom and a nitrogen atom as ring forming atoms.

10. The mixed layer of claim 1, wherein the mixed layer is an emission layer, and
each of the first dopant and the second dopant is an emitter;
the first dopant is an emitter, and the second dopant is a sensitizer; or
the first dopant is a sensitizer, and the second dopant is an emitter.

11. The mixed layer of claim 1, wherein the mixed layer is an emission layer, and
each of the first dopant and the second dopant emits red light;
each of the first dopant and the second dopant emits green light; or
each of the first dopant and the second dopant emits blue light.

12. A method of preparing the mixed layer of claim 1, the method comprising:
preparing:
a substrate,
a first deposition source comprising the first dopant and the second dopant,
a second deposition source comprising the matrix material, and
a vapor-state dopant composition provision unit configured to provide a vapor-state dopant composition from the first deposition source, wherein the vapor-state dopant composition comprises a vapor-state first dopant and a vapor-state second dopant;
preparing a deposition source moving unit on which the first deposition source and the second deposition source are arranged with a distance therebetween such that a region wherein the vapor-state dopant composition is present overlaps a region wherein a vapor-state matrix material is present, the vapor-state matrix material being released from the second deposition source;
arranging the deposition source moving unit at a first end below a surface of the substrate such that the substrate faces the deposition source moving unit; and
depositing the matrix material, the first dopant, and the second dopant on the surface of the substrate by
performing a one-way process of moving the deposition source moving unit in a direction away from the first end below the surface of the substrate toward a second end, or
performing, one or more times, a reciprocating process of moving the deposition source moving unit in a direction away from the first end below the surface of the substrate and toward a second end, and then immediately moving the deposition source moving unit in a direction away from the second end and toward the first end,
wherein the first deposition source comprises a first region and a second region, wherein the first region comprises the first dopant and does not comprise the second dopant, and wherein the second region comprises the second dopant and does not comprise the first dopant, wherein the first dopant and the second dopant in the first deposition source are not mixed with each other.

13. The method of claim 12, wherein the first deposition source further comprises a separation unit configured to separate the first region and the second region.

14. The method of claim 12, wherein the vapor-state dopant composition provision unit comprises:
a first unit configured to form the vapor-state dopant composition; and
a second unit configured to discharge the vapor-state dopant composition from the first unit.

15. The method of claim 12, wherein a deposition temperature of the depositing is less than a melting point of the first dopant, and
when a pre-mixed composition of the first dopant and the second dopant is crystalline, the deposition temperature of the depositing is greater than a melting point of the pre-mixed composition, and
when the pre-mixed composition of the first dopant and the second dopant is amorphous, the deposition temperature of the depositing is greater than a fusion temperature of the pre-mixed composition.

16. A light-emitting device, comprising:
a first electrode;
a second electrode facing the first electrode; and
an interlayer arranged between the first electrode and the second electrode,
wherein the interlayer comprises the mixed layer of claim 1.

17. The light-emitting device of claim 16, wherein the mixed layer is an emission layer.

18. The light-emitting device of claim 16, wherein the interlayer comprises:
m light-emitting units that comprise at least one emission layer; and
m−1 charge generation layers arranged between two neighboring light-emitting units of the m light-emitting units,
wherein m is an integer of 2 or greater, and
at least one light-emitting unit of the m light-emitting units comprises the mixed layer of claim 1.

19. The light-emitting device of claim 18, wherein the at least one light-emitting unit of the m light-emitting units emits green light, and
at least one light-emitting unit of the remaining light-emitting units emits blue light.

20. An electronic apparatus, comprising the light-emitting device of claim 16.
